(19) United States
(12) Patent Application Publication
(10) Pub. No.: US 2023/0081897 A1
(43) Pub. Date: Mar. 16, 2023

(54) POLYCYCLIC COMPOUND AND ORGANIC LIGHT-EMITTING DEVICE INCLUDING THE SAME

(71) Applicants: Samsung Electronics Co., Ltd., Suwon-si (KR); Kwangwoon University Industry-Academic Collaboration Foundation, Seoul (KR)

(72) Inventors: Sangmo Kim, Hwaseong-si (KR); Yunmi Lee, Seoul (KR); Juhyun Kim, Seoul (KR); Jiwhan Kim, Seoul (KR); Yusuke MARUYAMA, Hwaseong-si (KR); Dmitry ANDROSOV, Suwon-si (KR); Soonok Jeon, Suwon-si (KR); Hyeonho Choi, Seoul (KR); Sangback Lee, Seoul (KR); Hanseul Lee, Seoul (KR)

(21) Appl. No.: 17/469,497

(22) Filed: Sep. 8, 2021

(30) Foreign Application Priority Data
Sep. 15, 2020 (KR) 10-2020-0118377

(51) Int. Cl. C07F 5/02; H01L 51/00

(52) U.S. Cl. CPC C07F 5/02; H01L 51/5004; H01L 51/0072; H01L 51/008

(57) ABSTRACT

A polycyclic compound represented by Formula 1:

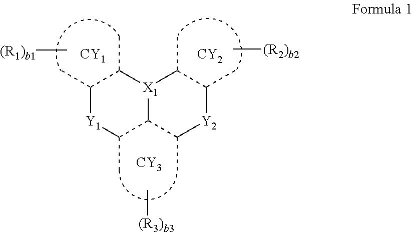

wherein, in Formulae 1, ring CY₁, ring CY₂, and ring CY₃ are each independently a C₅-C₃₀ carbocyclic group or a C₁-C₃₀ heterocyclic group; X₁ is B, N, P, P(═O), P(═S), Al, Ga, As, C(R₄), Si(R₄), or Ge(R₄); Y₁ and Y₂ are each independently O, S, Se, B(R₅), N(R₅), C(R₅)(R₆), Si(R₅)(R₆), Ge(R₅)(R₆), Ga(R₅), As(R₅) P(R₅), P(═O)(R₅), P(═S)(R₅), or Al(R₅); and R₁, R₂, R₃, b1, b2, and b3 are as provided herein.

### CROSS-REFERENCE TO RELATED APPLICATION

This application claims priority to and the benefit of Korean Patent Application No. 10-2020-0118377, filed on Sep. 15, 2020, in the Korean Intellectual Property Office, and all the benefits accruing therefrom under 35 U.S.C. § 119, the content of which is incorporated by reference herein in its entirety.

### BACKGROUND

### 1. Field

One or more embodiments relate to a polycyclic compound and an organic light-emitting device including the same.

### 2. Description of Related Art

Organic light-emitting devices (OLEDs) are self-emission devices that produce full-color images, and also have wide viewing angles, high contrast ratios, short response times, and excellent characteristics in terms of brightness, driving voltage, and response speed, compared to devices in the art.

In an example, an organic light-emitting device includes an anode, a cathode, and an organic layer located between the anode and the cathode, wherein the organic layer includes an emission layer. A hole transport region may be located between the anode and the emission layer, and an electron transport region may be located between the emission layer and the cathode. Holes provided from the anode may move toward the emission layer through the hole transport region, and electrons provided from the cathode may move toward the emission layer through the electron transport region. The holes and the electrons then recombine in the emission layer to produce excitons in an excited state. The excitons transition from the excited state to a ground state to thereby generate light.

### SUMMARY

One or more embodiments include an organic light-emitting device (OLED) having high efficiency and high color purity.

Additional aspects will be set forth in part in the description which follows and, in part, will be apparent from the description, or may be learned by practice of the presented exemplary embodiments of the disclosure.

An aspect of the present disclosure provides a polycyclic compound represented by Formula 1.

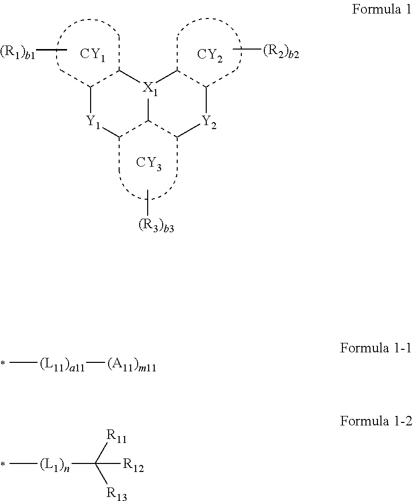

In Formulae 1, 1-1, and 1-2,
ring CY₁, ring CY₂, and ring CY₃ are each independently be a C₅-C₃₀ carbocyclic group or a C₁-C₃₀ heterocyclic group,
X₁ is B, N, P, P(O), P(S), Al, Ga, As, C(R₄), Si(R₄), or Ge(R₄),
Y₁ and Y₂ are each independently O, S, Se, B(R₅), N(R₅), C(R₅)(R₆), Si(R₅)(R₆), Ge(R₅)(R₆), Ga(R₅), As(R₅) P(R₅), P(O)(R₅), P(S)(R₅), or Al(R₅),
R₁, R₂, R₃, R₄, R₅, and R₆ are each independently a group represented by Formula 1-1, hydrogen, deuterium, —F, —Cl, —Br, —I, —SF₅, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₇-C₆₀ alkyl aryl group, a substituted or unsubstituted C₆-C₆₀ aryloxy group, a substituted or unsubstituted C₆-C₆₀ arylthio group, a substituted or unsubstituted C₇-C₆₀ aryl alkyl group, a substituted or unsubstituted C₁-C₆₀ heteroaryl group, a substituted or unsubstituted C₁-C₆₀ heteroaryloxy group, a substituted or unsubstituted C₁-C₆₀ heteroarylthio group, a substituted or unsubstituted C₂-C₆₀ heteroarylalkyl group, a substituted or unsubstituted monovalent non-aromatic condensed polycyclic group, a substituted or unsubstituted monovalent non-aromatic condensed heteropolycyclic group, —N(Q₁)(Q₂), —Si(Q₃)(Q₄)(Q₅), —B(Q₆)(Q₇), or —P(═O)(Q₆)(Q₉),
at least one of R₁ to R₆ is a group represented by Formula 1-1,
two adjacent groups of R₁ to R₆ are optionally bonded to each other to form a substituted or unsubstituted C₅-C₃₀ carbocyclic group or a substituted or unsubstituted C₁-C₃₀ heterocyclic group,
b1 to b3 re each independently an integer of 0 to 10,
when b1 is 2 or more, two or more of R₁(s) are identical to or different from each other, when b2 is 2 or more, two or more of R₂(s) are identical to or different from each other, when b3 is 2 or more, two or more of R₃(s) are identical to or different from each other,
L₁₁ is a single bond, a substituted or unsubstituted C₅-C₃₀ carbocyclic group, or a substituted or unsubstituted C₁-C₃₀ heterocyclic group,
a11 is an integer from 1 to 3,
A₁₁ is a group represented by Formula 1-2.
m11 is an integer from 1 to 5,
L₁ is a substituted or unsubstituted C₁-C₂₀ alkylene group, a substituted or unsubstituted C₂-C₂₀ alkenylene group, a substituted or unsubstituted C₃-C₁₀ cycloalkylene group, a substituted or unsubstituted C₁-C₁₀ heterocycloalkylene group, a substituted or unsubstituted C₃-C₁₀ cycloalkenylene group, a substituted or unsubstituted C₁-C₁₀ heterocycloalkenylene group, a substituted or unsubstituted C₆-C₆₀ arylene group, a substituted or unsubstituted C₁-C₆₀ heteroarylene group, a substituted or unsubstituted divalent non-aromatic condensed polycyclic group, or a substituted or unsubstituted divalent non-aromatic condensed heteropolycyclic group,
n is an integer from 0 to 3, wherein, when n is 0, L₁ is not present, and when n is 2 or more, two or more of L₁ (s) are identical to or different from each other,
R₁₁, R₁₂, and R₁₃ are each independently hydrogen, deuterium, —F, —Cl, —Br, —I, —SF₅, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₇-C₆₀ alkyl aryl group, a substituted or unsubstituted C₆-C₆₀ aryloxy group, a substituted or unsubstituted C₆-C₆₀ arylthio group, a substituted or unsubstituted C₇-C₆₀ aryl alkyl group, a substituted or unsubstituted C₁-C₆₀ heteroaryl group, a substituted or unsubstituted C₁-C₆₀ heteroaryloxy group, a substituted or unsubstituted C₇-C₆₀ heteroarylthio group, a substituted or unsubstituted C₁-C₆₀ heteroarylalkyl group, a substituted or unsubstituted monovalent non-aromatic condensed polycyclic group, a substituted or unsubstituted monovalent non-aromatic condensed heteropolycyclic group, —N(Q₁)(Q₂), —Si(Q₃)(Q₄)(Q₅), —B(Q₆)(Q₇), or —P(═O)(Q₈)(Q₅),
at least one of R₁₁, R₁₂, and R₁₃ is a substituted or unsubstituted C₆-C₆₀ aryl group,
and *′ each indicates a binding site to a neighboring group, and
at least one substituent of the substituted C₅-C₃₀ carbocyclic group, the substituted C₁-C₃₀ heterocyclic group, the substituted C₁-C₆₀ alkyl group, the substituted C₂-C₆₀ alkenyl group, the substituted C₂-C₆₀ alkynyl group, the substituted C₁-C₆₀ alkoxy group, the substituted C₃-C₁₀ cycloalkyl group, the substituted C₁-C₁₀ heterocycloalkyl group, the substituted C₃-C₁₀ cycloalkenyl group, the substituted C₁-C₁₀ heterocycloalkenyl group, the substituted C₆-C₆₀ aryl group, the substituted C₇-C₆₀ alkyl aryl group, the substituted C₆-C₆₀ aryloxy group, the substituted C₆-C₆₀ arylthio group, the substituted C₇-C₆₀ aryl alkyl group, the substituted C₁-C₆₀ heteroaryl group, the substituted C₁-C₆₀ heteroaryloxy group, the substituted C₁-C₆₀ heteroarylthio group, the substituted C₂-C₆₀ heteroarylalkyl group, the substituted monovalent non-aromatic condensed polycyclic group, the substituted monovalent non-aromatic condensed heteropolycyclic group, the substituted C₁-C₂₀ alkylene group, the substituted C₂-C₂₀ alkenylene group, the substituted C₃-C₁₀ cycloalkylene group, the substituted C₁-C₁₀ heterocycloalkylene group, the substituted C₃-C₁₀ cycloalkenylene group, the substituted C₁-C₁₀ heterocycloalkenylene group, the substituted C₆-C₆₀ arylene group, the substituted C₂-C₆₀ heteroarylene group, the substituted divalent non-aromatic condensed polycyclic group, and the substituted divalent non-aromatic condensed heteropolycyclic group may be:
deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₆₀ alkyl group, a C₂-C₆₀ alkenyl group, a C₂-C₆₀ alkynyl group, or a C₁-C₆₀ alkoxy group,
a C₁-C₆₀ alkyl group, a C₂-C₆₀ alkenyl group, a C₂-C₆₀ alkynyl group, or a C₁-C₆₀ alkoxy group, each substituted with at least one of deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₆-C₆₀ aryl alkyl group, a C₁-C₆₀ heteroaryl group, a C₁-C₆₀ heteroaryloxy group, a C₁-C₆₀ heteroarylthio group, a C₂-C₆₀ heteroarylalkyl group, a monovalent non-aromatic condensed polycyclic group, a monovalent non-aromatic condensed heteropolycyclic group, —Si(Q₁₁)(Q₁₂)(Q₁₃), —N(Q₁₄)(Q₁₅), —B(Q₁₆)(Q₁₇), or —P(═O)(Q₁₈)(Q₁₉),
a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₆-C₆₀ aryloxy group, a C₆-C₆₀ arylthio group, a C₇-C₆₀ aryl alkyl group, a C₁-C₆₀ heteroaryl group, a C₁-C₆₀ heteroaryloxy group, a C₁-C₆₀ heteroarylthio group, a C₂-C₆₀ heteroarylalkyl group, a monovalent non-aromatic condensed polycyclic group, or a monovalent non-aromatic condensed heteropolycyclic group,
a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₆-C₆₀ aryloxy group, a C₆-C₆₀ arylthio group, a C₁-C₆₀ aryl alkyl group, a C₁-C₆₀ heteroaryl group, a C₁-C₆₀ heteroaryloxy group, a C₁-C₆₀ heteroarylthio group, a C₂-C₆₀ heteroarylalkyl group, a monovalent non-aromatic condensed polycyclic group, or a monovalent non-aromatic condensed heteropolycyclic group, each substituted with at least one of deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₂-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₆-C₆₀ aryloxy group, a C₆-C₆₀ arylthio group, a C₇-C₆₀ aryl alkyl group, a C₁-C₆₀ heteroaryl group, a C₁-C₆₀ heteroaryloxy group, a C₇-C₆₀ heteroarylthio group, a C₂-C₆₀ heteroarylalkyl group, a monovalent non-aromatic condensed polycyclic group, a monovalent non-aromatic condensed heteropolycyclic group, —Si(Q₂₁)(Q₂₂)(Q₂₃), —N(Q₂₄)(Q₂₅) —B(Q₂₆)(Q₂₇), or —P(═O)(Q₂₈)(Q₂₉), or
—Si(Q₃₁)(Q₃₂)(Q₃₃), —N(Q₃₄)(Q₃₅), —B(Q₃₆)(Q₃₇), or —P(═O)(Q₃₈)(Q₃₉),
wherein Q₁ to Q₉, Q₁₁ to Q₁₉, Q₂₁ to Q₂₉, and Q₃₁ to Q₃₉ may each independently be hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₂-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₁-C₆₀ alkyl aryl group, a substituted or unsubstituted C₆-C₆₀ aryloxy group, a substituted or unsubstituted C₆-C₆₀ arylthio group, a substituted or unsubstituted C₇-C₆₀ aryl alkyl group, a substituted or unsubstituted C₁-C₆₀ heteroaryl group, substituted or unsubstituted C₁-C₆₀ heteroaryloxy group, a substituted or unsubstituted C₁-C₆₀ heteroarylthio group, a substituted or unsubstituted C₂-C₆₀ heteroarylalkyl group, a substituted or unsubstituted monovalent non-aromatic condensed polycyclic group, or a substituted or unsubstituted monovalent non-aromatic condensed heteropolycyclic group.

Another aspect provides an organic light-emitting device including a first electrode, a second electrode, and an organic layer located between the first electrode and the second electrode and including an emission layer, wherein the organic layer includes at least one type of the polycyclic compounds.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 shows a schematic cross-sectional view of an organic light-emitting device according to one or more embodiments;

FIG. 2 is a graph of intensity (arbitrary units, a.u.) versus wavelength (nanometers, nm) and shows a light emission curve of light emitted when excited singlet energy and excited triplet energy of the organic light-emitting device manufactured according to Example 1 is converted to a ground state;

FIG. 3 is a graph of intensity (a.u.) versus wavelength (nm) and shows a light emission curve of light emitted when excited singlet energy and excited triplet energy of the organic light-emitting device manufactured according to Comparative Example 1 is converted to a ground state; and

FIG. 4 is a graph of intensity (a.u.) versus wavelength (nm) and shows a light emission curve of light emitted when excited singlet energy and excited triplet energy of the organic light-emitting device manufactured according to Comparative Example 2 is converted to a ground state.

### DETAILED DESCRIPTION

Reference will now be made in detail to exemplary embodiments, examples of which are illustrated in the accompanying drawings, wherein like reference numerals refer to like elements throughout. In this regard, the present embodiments may have different forms and should not be construed as being limited to the descriptions set forth herein. Accordingly, the exemplary embodiments are described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

The terminology used herein is for the purpose of describing one or more exemplary embodiments only and is not intended to be limiting. As used herein, the singular forms “a,” “an,” and “the” are intended to include the plural forms as well, unless the context clearly indicates otherwise. The term “or” means “and/or.” It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that, although the terms first, second, third etc. may be used herein to describe various elements, components, regions, layers, and/or sections, these elements, components, regions, layers, and/or sections should not be limited by these terms. These terms are only used to distinguish one element, component, region, layer, or section from another element, component, region, layer, or section. Thus, a first element, component, region, layer, or section discussed below could be termed a second element, component, region, layer, or section without departing from the teachings of the present embodiments.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

It will be understood that when an element is referred to as being “on” another element, it can be directly in contact with the other element or intervening elements may be present therebetween. In contrast, when an element is referred to as being “directly on” another element, there are no intervening elements present.

Unless otherwise defined, all terms (including technical and scientific terms) used herein have the same meaning as commonly understood by one of ordinary skill in the art to which this general inventive concept belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10%, 5% of the stated value.

An aspect of the present disclosure provides a polycyclic compound represented by Formula 1:

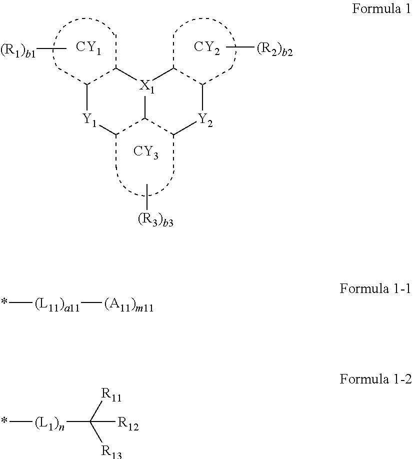

wherein CY₁, ring CY₂, an ring CY₃ in Formula 1 are each independently a C₅-C₃₀ carbocyclic group or a C₁-C₃₀ heterocyclic group.

In one or more embodiments, ring CY₁, ring CY₂, and ring CY₃ may each independently be:
group A,
group B,
a condensed ring in which two or more of group A are condensed with each other,
a condensed ring in which two or more of group B are condensed with each other, or
a condensed ring in which at least one of group A is condensed with at least one of group B, but embodiments of the present disclosure are not limited thereto:
wherein group A may be a cyclic diene group (for example, cyclopenta-1,3-diene group), an indene group, an azulene group, a benzene group, a naphthalene group, an anthracene group, a phenanthrene group, a tetracene group, a tetraphene group, a pyrene group, a chrysene group, a triphenylene group, or a fluorene group, and
wherein group B may be a furan group, a thiophene group, a pyrrole group, borole group, a silole group, a pyrrolidine group, an imidazole group, a triazole group, an oxazole group, an isoxazole group, a thiazole group, an isothiazole group, a pyridine group, a pyrimidine group, a pyidazine group, a triazine group, an indole group, an isoindole group, an indolizine group, a quinoline group, an isoquinoline group, a quinoxaline group, an isoquinoxaline group, a carbazole group, a dibenzofuran group, a dibenzothiophene group, a dibenzosilole group, or a dibenzoborole group.

For example, ring CY₁, ring CY₂, and ring CY₃ may each independently be a benzene group, a naphthalene group, an anthracene group, or a fluorene group.

For example, ring CY₁, ring CY₂, and ring CY₃ may be the same. For example, ring CY₁, ring CY₂, and ring CY₃ may each be a benzene group.

X₁ in Formula 1 is B, N, P, P(═O), P(═S), Al, Ga, As, C(R₄), Si(R₄), or Ge(R₄).

In one or more embodiments, X₁ may be B, N, P, P(═O), P(═S), or Al, but embodiments of the present disclosure are not limited thereto. For example, X₁ may be B.

Y₁ and Y₂ in Formula 1 are each independently O, S, Se, B(R₅), N(R₅), C(R₅)(R₆), Si(R₅)(R₆), Ge(R₅)(R₆), Ga(R₅), As(R₅) P(R₅), P(O)(R₅), P(S)(R₅), or Al(R₅).

In one or more embodiments, Y₁ and Y₂ may each independently be O, S, Se, B(R₅), N(R₅), C(R₅)(R₆), or Si(R₅)(R₆). For example, Y₁ and Y₂ may be identical to each other. For example, Y₁ and Y₂ may each be N(R₅).

In one or more embodiments, X₁ may be:
B, N, P, P(O), P(S), or Al, and
Y₁ and Y₂ may each independently be O, S, Se, B(R₅), N(R₅), C(R₅)(R₆), or Si(R₅)(R₆).

L₁₁ in Formula 1-1 is a single bond, a substituted or unsubstituted C₅-C₃₀ carbocyclic group, or a substituted or unsubstituted C₁-C₆₀ heterocyclic group.

In one or more embodiments, L₁₁ may be:
a single bond;
a benzene group, an indene group, a naphthalene group, an azulene group, a heptalene group, acenaphthylene group, a fluorene group, a phenalene group, a phenanthrene group, an anthracene group, a fluoranthene group, a triphenylene group, a pyrene group, a chrysene group, a pyridine group, a pyrimidine group, a pyrazine group, a quinoline group, an isoquinoline group, a benzoquinoline group, a phthalazine group, a naphthyridine group, a quinoxaline group, a quinazoline group, a cinnoline group, a phenanthridine group, an acridine group, a phenanthroline group, a phenazine group, a benzimidazole group, an isobenzothiazole group, a benzoxazole group, a benzoisoxazole group, a triazole group, a tetrazole group, an oxadiazole group, a triazine group, a thiadiazole group, an imidazopyridine group, an imidazopyrimidine group, a carbazole group, an azacarbazole group, a dibenzofuran group, a dibenzothiophene group, or a dibenzosilole group; or
a benzene group, an indene group, a naphthalene group, an azulene group, a heptalene group, acenaphthylene group, a fluorene group, a phenalene group, a phenanthrene group, an anthracene group, a fluoranthene group, a triphenylene group, a pyrene group, a chrysene group, a pyridine group, a pyrimidine group, a pyrazine group, a quinoline group, an isoquinoline group, a benzoquinoline group, a phthalazine group, a naphthyridine group, a quinoxaline group, a quinazoline group, a cinnoline group, a phenanthridine group, an acridine group, a phenanthroline group, a phenazine group, a benzimidazole group, an isobenzothiazole group, a benzoxazole group, a benzoisoxazole group, a triazole group, a tetrazole group, an oxadiazole group, a triazine group, a thiadiazole group, an imidazopyridine group, an imidazopyrimidine group, a carbazole group, an azacarbazole group, a dibenzofuran group, a dibenzothiophene group, or dibenzosilole group, each substituted with at least one of deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ cycloalkenyl group, a C₁-C₁₀ heterocycloalkyl group, a C₁-C₁₀ heterocycloalkenyl group, a C₆-C₆₀ aryl group, a C₇-C₆₀ alkyl aryl group, a C₆-C₆₀ aryloxy group, a C₆-C₆₀ arylthio group, a C₇-C₆₀ aryl alkyl group, a C₁-C₆₀ heteroaryl group, a C₁-C₆₀ heteroaryloxy group, a C₁-C₆₀ heteroarylthio group, a C₂-C₆₀ heteroarylalkyl group, a monovalent non-aromatic condensed polycyclic group, or a monovalent non-aromatic condensed heteropolycyclic group, but embodiments of the present disclosure are not limited thereto.

For example, L₁₁ may be a single bond or a group represented by one of Formulae 3-1 to 3-46:

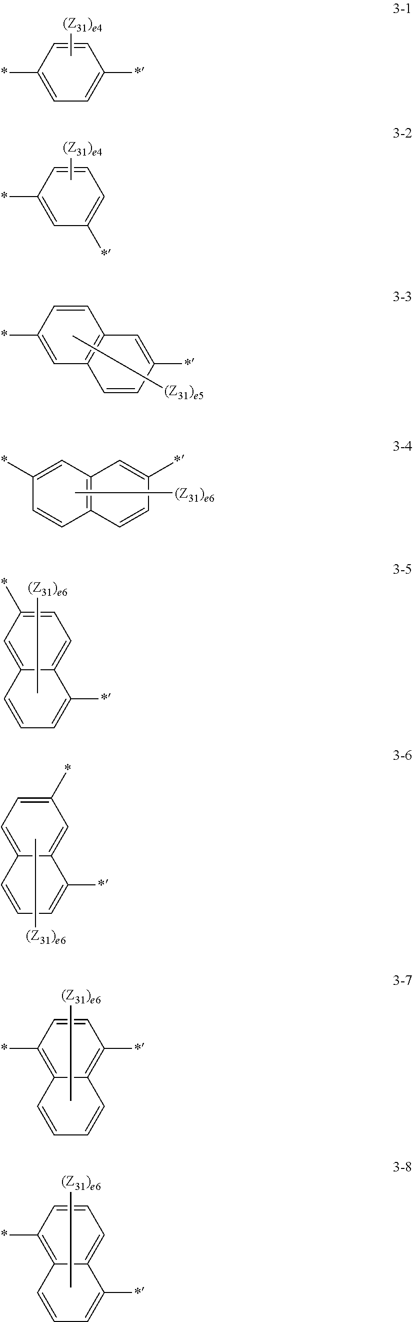

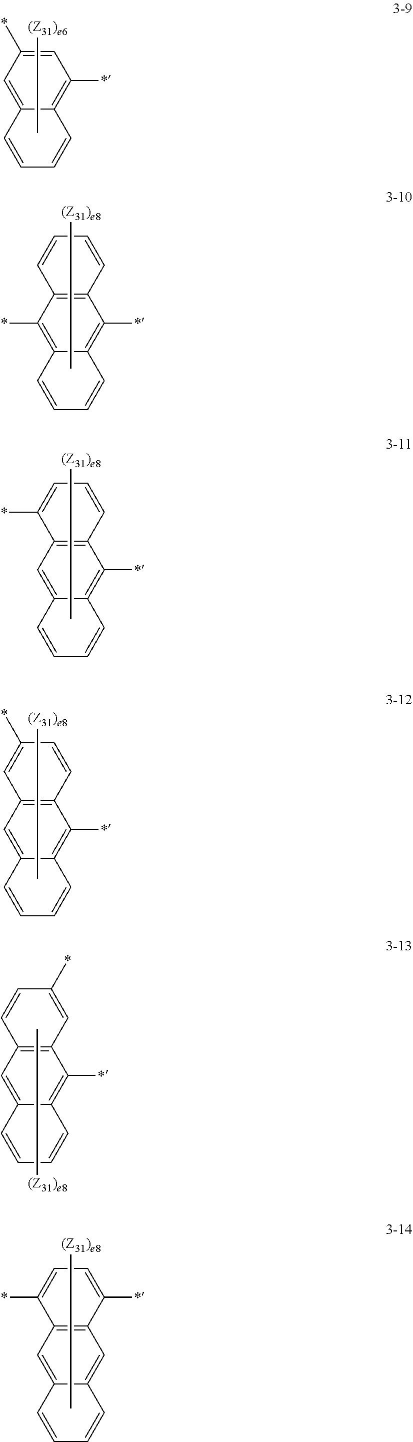

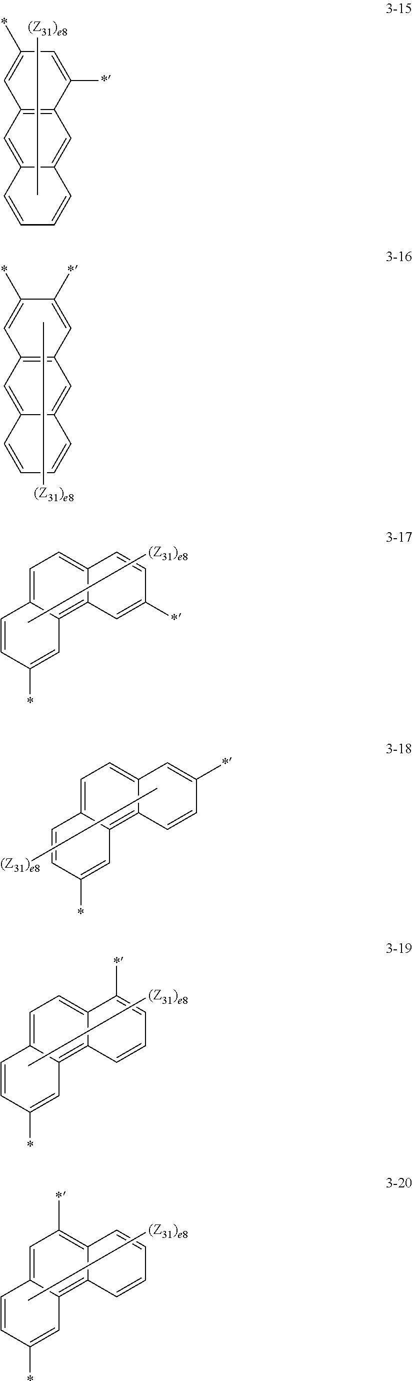

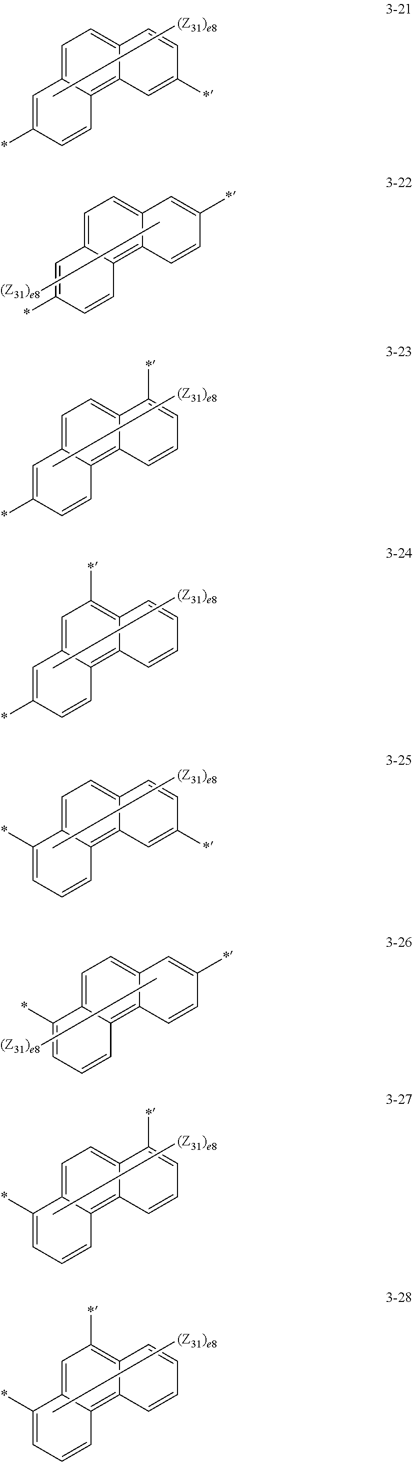

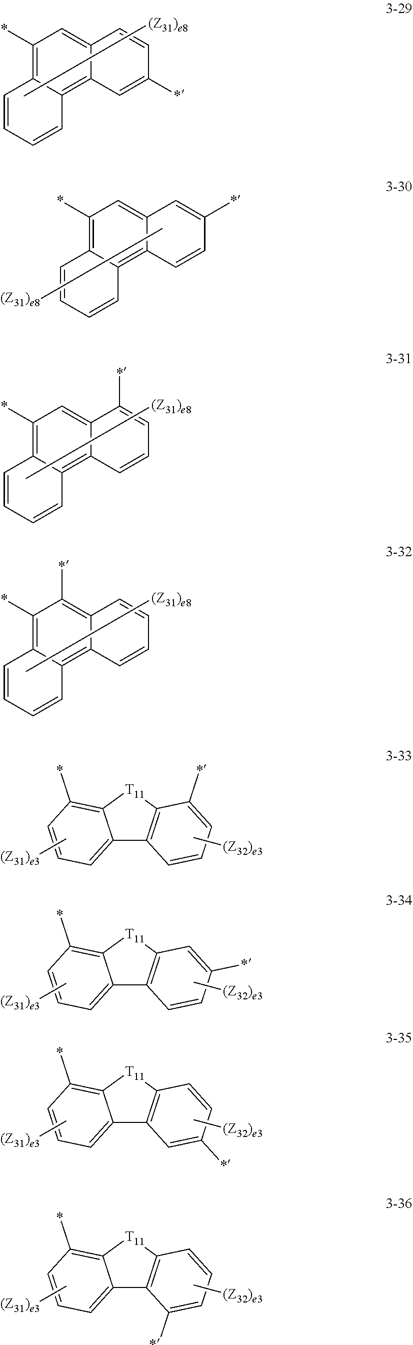

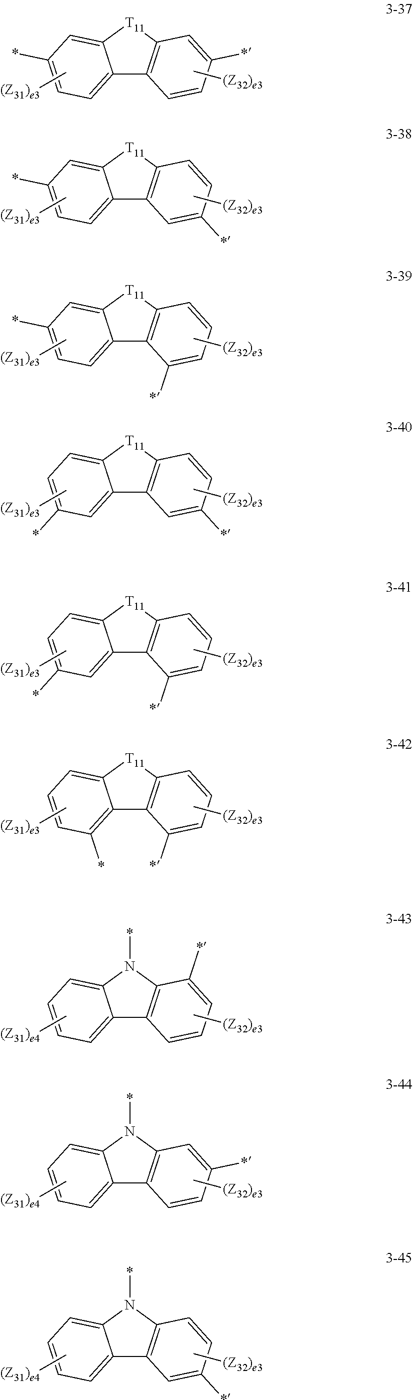

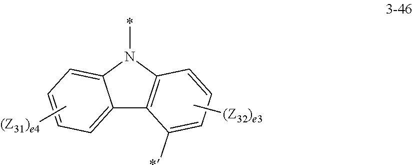

wherein, in Formulae 3-1 to 3-46,
T₁₁ may be O, S, Si(Z₃₃)(Z₃₄), C(Z₃₃)(Z₃₄), or Se,
Z₃₁ to Z₃₄ may each independently be hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ cycloalkenyl group, a C₁-C₁₀ heterocycloalkyl group, a C₁-C₁₀ heterocycloalkenyl group, a C₆-C₆₀ aryl group, a C₇-C₆₀ alkyl aryl group, a C₆-C₆₀ aryloxy group, a C₆-C₆₀ arylthio group, a Cr-Coo aryl alkyl group, or a C₁-C₆₀ heteroaryl group,
e3 may be an integer from 1 to 3,
e4 may be an integer from 1 to 4,
e6 may be an integer from 1 to 6,
e8 may be an integer from 1 to 8, and
* and *′ each indicate a binding site to a neighboring atom.

a11 in Formula 1-1 indicates the number of L₁₁ groups, and is an integer from 1 to 3. For example, when a11 is the integer of 2 or more, two or more of L₁₁ groups may be identical to or different from each other.

A₁₁ in Formula 1-1 is a group represented by Formula 1-2, and m11 is an integer from 1 to 5. For example, m11 may be 1 or 2.

In one or more embodiments, m11 may be the number of A₁₁ groups or the number of groups represented by Formula 1-2 bonding to Formula 1 (in the case where L₁₁ is a single bond), and may be 1, 2, 3, or 4. For example, when m11 is 2 or more, two or more of groups represented by Formula 1-2 may be identical to or different from each other.

In one or more embodiments, m11 is 2, and two groups represented by Formula 1-2 may be identical to each other.

L₁ in Formula 1-2 is a substituted or unsubstituted C₁-C₂₀ alkylene group, a substituted or unsubstituted C₂-C₂₀ alkenylene group, a substituted or unsubstituted C₃-C₁₀ cycloalkylene group, a substituted or unsubstituted C₁-C₁₀ heterocycloalkylene group, a substituted or unsubstituted C₃-C₁₀ cycloalkenylene group, a substituted or unsubstituted C₁-C₁₀ heterocycloalkenylene group, a substituted or unsubstituted C₆-C₆₀ arylene group, a substituted or unsubstituted C₁-C₆₀ heteroarylene group, a substituted or unsubstituted divalent non-aromatic condensed polycyclic group, or a substituted or unsubstituted divalent non-aromatic condensed heteropolycyclic group.

In one or more embodiments, L₁ may be a single bond or group represented by one of Formulae 3-1 to 3-46.

In in Formula 1-2 indicates the number of L₁ (s), and is an integer from 0 to 3, wherein, when n is 0, L₁ is not present, and when n is 2 or more, two or more of L₁ (s) may be identical to or different from each other.

In one or more embodiments, L₁₁ and L₁ may be identical to or different from each other. For example, one of L₁₁ and L₁ may be a single bond. For example, L₁₁ and L₁ may each be a single bond.

R₁, R₂, R₃, R₄, R₅ and R₆ in Formula 1 may each independently be a group represented by Formula 1-1, hydrogen, deuterium, —F, —Cl, —Br, —I, —SF₅, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₇-C₆₀ alkyl aryl group, a substituted or unsubstituted C₆-C₆₀ aryloxy group, a substituted or unsubstituted C₆-C₆₀ arylthio group, a substituted or unsubstituted C₇-C₆₀ aryl alkyl group, a substituted or unsubstituted C₁-C₆₀ heteroaryl group, substituted or unsubstituted C₁-C₆₀ heteroaryloxy group, a substituted or unsubstituted C₁-C₆₀ heteroarylthio group, a substituted or unsubstituted C₂-C₆₀ heteroarylalkyl group, a substituted or unsubstituted monovalent non-aromatic condensed polycyclic group, a substituted or unsubstituted monovalent non-aromatic condensed heteropolycyclic group, —N(Q₁)(Q₂), —Si(Q₃)(Q₄)(Q₅), —B(Q₆)(Q₇), or —P(═O)(Q₈)(Q₆).

In one or more embodiments, R₁, R₂, R₃, R₄, R₅, and R₆ may each independently be:
a group represented by Formula 1-1;
hydrogen, deuterium, —F, —Cl, —Br, —I, a hydroxyl group, a cyano group (CN), a nitro group, an amino group, a C₁-C₆₀ alkyl group, or a C₁-C₆₀ alkoxy group;
a C₁-C₆₀ alkyl group or a C₁-C₆₀ alkoxy group, each substituted with at least one of deuterium, —F, —Cl, —Br, —I, a hydroxyl group, a cyano group (CN), a nitro group, an amino group, a phenyl group, a biphenyl group, a naphthyl group, a fluorenyl group, a phenanthrenyl group, an anthracenyl group, a fluoranthenyl group, a triphenylenyl group, a pyrenyl group, or a chrysenyl group:
a cyclopentyl group, a cyclohexyl group, a cycloheptyl group, a cyclopentenyl group, a cyclohexenyl group, a cycloheptenyl group, a phenyl group, a biphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a phenanthrolinyl group, a benzimidazolyl group, a benzofuranyl group, a benzothiophenyl group, a benzoisothiazolyl group, a benzoxazolyl group, an isobenzoxazolyl group, a thazolyl group, a tetrazolyl group, an oxadiazolyl group, a triazinyl group, a dibenzofuranyl group, a dibenzothiophenyl group, or a carbazolyl group; or
a cyclopentyl group, a cyclohexyl group, a cycloheptyl group, a cyclopentenyl group, a cyclohexenyl group, a cycloheptenyl group, a phenyl group, a biphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a phenanthrolinyl group, a benzimidazolyl group, a benzofuranyl group, a benzothiophenyl group, a benzoisothiazolyl group, a benzoxazolyl group, an isobenzoxazolyl group, a thazolyl group, a tetrazolyl group, an oxadiazolyl group, a triazinyl group, a dibenzofuranyl group, a dibenzothiophenyl group, or a carbazolyl group, each substituted with at least one of deuterium, —F, —Cl, —Br, —I, a hydroxyl group, a cyano group, a nitro group, an amino group, a C₁-C₆₀ alkyl group, a C₇-C₆₀ aryl alkyl group, a C₁-C₆₀ alkoxy group, a cyclopentyl group, a cyclohexyl group, a cycloheptyl group, a cyclopentenyl group, a cyclohexenyl group, a cycloheptenyl group, a phenyl group, a biphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyrdazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a phenanthrolinyl group, a benzimidazolyl group, a benzofuranyl group, a benzothiophenyl group, a benzoisothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, or a carbazolyl group, but embodiments of the present disclosure are not limited thereto.

For example, R₁, R₂, R₃, R₄, R₅, and R₆ may each independently be:
a group represented by Formula 1-1;
hydrogen, deuterium, —F, —Cl, —Br, —I, a hydroxyl group, a cyano group, a nitro group, an amino group, a methyl group, an ethyl group, a propyl group, an isopropyl group, a butyl group, a sec-butyl group, an isobutyl group, a tert-butyl group, a methoxy group, an ethoxy group, a propoxy group, an isopropoxy group, a butoxy group, a sec-butoxy group, a tert-butoxy group, or an isobutoxy group;
a methyl group, an ethyl group, a propyl group, an isopropyl group, a butyl group, a sec-butyl group, an isobutyl group, a tert-butyl group, a methoxy group, an ethoxy group, a propoxy group, an isopropoxy group, a butoxy group, a sec-butoxy group, a tert-butoxy group, or an isobutoxy group, each substituted with at least one of deuterium, —F, —Cl, —Br, —I, a hydroxyl group, a cyano group (CN), a nitro group, an amino group, a phenyl group, a biphenyl group, a naphthyl group, a fluorenyl group, a phenanthrenyl group, an anthracenyl group, a fluoranthenyl group, a triphenylenyl group, a pyrenyl group, or a chrysenyl group;
a cyclopentyl group, a cyclohexyl group, a cycloheptyl group, a cyclopentenyl group, a cyclohexenyl group, a cycloheptenyl group, a phenyl group, a biphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a phenanthrolinyl group, a benzimidazolyl group, a benzofuranyl group, a benzothiophenyl group, a benzoisothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, or a carbazolyl group; or
a cyclopentyl group, a cyclohexyl group, a cycloheptyl group, a cyclopentenyl group, a cyclohexenyl group, a cycloheptenyl group, a phenyl group, a biphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a phenanthrolinyl group, a benzimidazolyl group, a benzofuranyl group, a benzothiophenyl group, a benzoisothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, or a carbazolyl group, each substituted with at least one of deuterium, —F, —Cl, —Br, —I, a hydroxyl group, a cyano group, a nitro group, an amino group, a methyl group, an ethyl group, a propyl group, an isopropyl group, a butyl group, a sec-butyl group, an isobutyl group, a tert-butyl group, a methoxy group, an ethoxy group, a propoxy group, an isopropoxy group, a butoxy group, a sec-butoxy group, a tert-butoxy group, isobutoxy group, a Cr-Coo aryl alkyl group, a cyclopentyl group, a cyclohexyl group, a cycloheptyl group, a cyclopentenyl group, a cyclohexenyl group, a cycloheptenyl group, a phenyl group, a biphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a phenanthrolinyl group, a benzimidazolyl group, a benzofuranyl group, a benzothiophenyl group, a benzoisothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, or a carbazolyl group, but embodiments of the present disclosure are not limited thereto.

at least one of R₁ to R₆ in Formula 1 is a group represented by Formula 1-1.

In one or more embodiments, two or more of R₁ to R₆ may be a group represented by Formula 1-1. In one or more embodiments, three or more of R₁ to R₆ may be a group represented by Formula 1-1. In one or more embodiments, four or more of R₁ to R₆ may be a group represented by Formula 1-1. In one or more embodiments, five or more of R₁ to R₆ may be a group represented by Formula 1-1. In one or more embodiments, six or more of R₁ to R₆ may be a group represented by Formula 1-1.

Two neighboring groups of R₁ to R₆ in Formula 1 may optionally be bonded to each other to form a substituted or unsubstituted C₅-C₃₀ carbocyclic group or a substituted or unsubstituted C₁-C₃₀ heterocyclic group.

For example, R₁ and R₂ in Formula 1 may be bonded to each other to form a C₅-C₃₀ carbocyclic group or a C₁-C₃₀ heterocyclic group, each unsubstituted or substituted with at least one R₁₀ₐ, in which an atom X₁, an atom constituting ring CY₁ and an atom constituting ring CY₂ are included therein.

R₁₀ may be the same as described in connection with R₁.

b1 to b3 in Formula 1 are each independently an integer from 0 to 10, wherein, when b1 is 2 or more, two or more of R₁(s) are identical to or different from each other, when b2 is 2 or more, two or more of R₂(s) are identical to or different from each other, and when b3 is 2 or more, two or more of R₃(s) are identical to or different from each other.

R₁₁, R₁₂, and R₁₃ in Formula 1-2 may each independently be hydrogen, deuterium, —F, —Cl, —Br, —I, —SF₅, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₇-C₆₀ alkyl aryl group, a substituted or unsubstituted C₆-C₆₀ aryloxy group, a substituted or unsubstituted C₆-C₆₀ arylthio group, a substituted or unsubstituted C₇-C₆₀ aryl alkyl group, a substituted or unsubstituted C₁-C₆₀ heteroaryl group, substituted or unsubstituted C₁-C₆₀ heteroaryloxy group, a substituted or unsubstituted C₁-C₆₀ heteroarylthio group, a substituted or unsubstituted C₂-C₆₀ heteroarylalkyl group, a substituted or unsubstituted monovalent non-aromatic condensed polycydic group, a substituted or unsubstituted monovalent non-aromatic condensed heteropolycyclic group, —N(Q₁)(Q₂), —Si(Q₃)(Q₄)(Q₅), —B(Q₆)(Q₇), or —P(═O)(Q₈)(Q₉), and at least one of R₁₁, R₁₂, and R₁₃ is a substituted or unsubstituted C₆-C₆₀ aryl group.

In one or more embodiments, R₁₁ to R₁₃ may each independently be:
hydrogen, deuterium, —F, —Cl, —Br, —I, a hydroxyl group, a cyano group (CN), a nitro group, an amino group, a C₁-C₆₀ alkyl group, or a C₁-C₆₀ alkoxy group;
a C₁-C₆₀ alkyl group or a C₁-C₆₀ alkoxy group, each substituted with at least one of deuterium, —F, —Cl, —Br, —I, a hydroxyl group, a cyano group, a nitro group, an amino group, a phenyl group, a biphenyl group, a naphthyl group, a fluorenyl group, a phenanthrenyl group, an anthracenyl group, a fluoranthenyl group, a triphenylenyl group, a pyrenyl group, or a chrysenyl group:
a cyclopentyl group, a cyclohexyl group, a cycloheptyl group, a cyclopentenyl group, a cyclohexenyl group, a cycloheptenyl group, a phenyl group, a biphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrmidinyl group, a pyrdazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a phenanthrolinyl group, a benzimidazolyl group, a benzofuranyl group, a benzothiophenyl group, a benzoisothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, or a carbazolyl group; or
a cyclopentyl group, a cyclohexyl group, a cycloheptyl group, a cyclopentenyl group, a cyclohexenyl group, a cycloheptenyl group, a phenyl group, a biphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a phenanthrolinyl group, a benzimidazolyl group, a benzofuranyl group, a benzothiophenyl group, a benzoisothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, or a carbazolyl group, each substituted with at least one of deuterium, —F, —Cl, —Br, —I, a hydroxyl group, a cyano group, a nitro group, an amino group, a C₁-C₆₀ alkyl group, a C₁-C₆₀ alkoxy group, a cyclopentyl group, a cyclohexyl group, a cycloheptyl group, a cyclopentenyl group, a cyclohexenyl group, a cycloheptenyl group, a phenyl group, a biphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a phenanthrolinyl group, a benzimidazolyl group, a benzofuranyl group, a benzothiophenyl group, a benzoisothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, or a carbazolyl group.

In one or more embodiments, m11 may be 1 or 2. For example, m11 may be 1.

In one or more embodiments, Formula 1-2 may be represented by one of Formulae 1-2a to 1-2c:

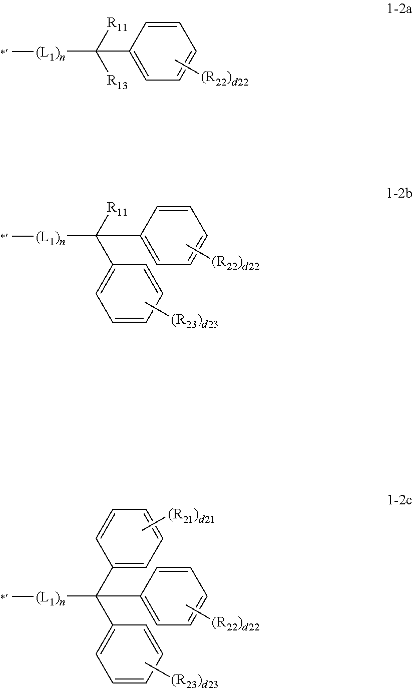

wherein, in Formulae 1-2a to 1-2c,
R₁₁, R₁₃, L₁, and n are each the same as described above,
R₂₁ to R₂₃ may each independently be:
hydrogen, deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₆-C₆₀ aryloxy group, a C₆-C₆₀ arylthio group, a C₇-C₆₀ aryl alkyl group, a C₁-C₆₀ heteroaryl group, a C₁-C₆₀ heteroaryloxy group, a C₁-C₆₀ heteroarylthio group, a C₂-C₆₀ heteroarylalkyl group, a monovalent non-aromatic condensed polycyclic group, a monovalent non-aromatic condensed heteropolycyclic group, —Si(Q₂₁)(Q₂₂)(Q₂₃), —N(Q₂₄)(Q₂₅) —B(Q₂₆)(Q₂₇), or —P(═O)(Q₂₈)(Q₂₉), and
d21 to d23 may each independently be an integer from 1 to 5, wherein when d21 is the integer of 2 or more, two or more of R₂₁(S) may be identical to or different from each other, when d22 is the integer of 2 or more, two or more of R₂₂(s) may be identical to or different from each other, and when d23 is the integer of 2 or more, two or more of R₂₃(s) may be identical to or different from each other.

For example, R₁₁ and R₁₃ in Formulae 1-2a and 1-2b may each independently be:
deuterium, —F, —Cl, —Br, —I, a hydroxyl group, a cyano group, a nitro group, an amino group, a C₁-C₆₀ alkyl group, or a C₁-C₆₀ alkoxy group; or
a C₁-C₆₀ alkyl group or a C₁-C₆₀ alkoxy group, each substituted with at least one of deuterium, —F, —Cl, —Br, —I, a hydroxyl group, a cyano group (CN), a nitro group, an amino group, a phenyl group, a biphenyl group, a naphthyl group, a fluorenyl group, a phenanthrenyl group, an anthracenyl group, a fluoranthenyl group, a triphenylenyl group, a pyrenyl group, or a chrysenyl group, but embodiments of the present disclosure are not limited thereto.

In one or more embodiments, n in Formulae 1-2a and 1-2b may be 0.

In one or more embodiments, Formula 1 may be represented by Formula 2 below:

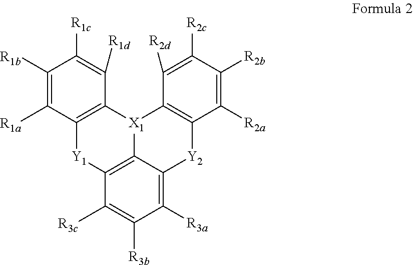

wherein, in Formula 2,
X₁, Y₁, and Y₂ are the same as described above,
R₁ₐ to R_{1d} are each the same as described in connection with R₁, and R₂ₐ to R_{2d} are each the same as described in connection with R₂, and R₃ₐ to R_{3c} are each the same as described in connection with R₃,
(i) one of R₁ₐ to R_{1d} may be a group represented by Formula 1-1; one of R₂ₐ to R_{2d} may be a group represented by Formula 1-1; one of R₃ₐ to R_{3c} may be a group represented by Formula 1-1;
(ii) two of R₁ₐ to R_{1d} may each be a group represented by Formula 1-1; two of R₂ₐ to R_{2d} may each be a group represented by Formula 1-1; two of R₃ₐ to R_{3c} may each be a group represented by Formula 1-1;
(i) three of R₁ₐ to R_{1d} may each be a group represented by Formula 1-1; three of R₂ₐ to R_{2d} may each be a group represented by Formula 1-1; each of R₃ₐ to R_{3c} may be a group represented by Formula 1-1;
(iv) each of R₁ₐ to R_{1d} is a group represented by Formula 1-1; or each of R₂ₐ to R_{2d} is a group represented by Formula 1-1;
(v) one of R₁ₐ to R_{1d} is a group represented by Formula 1-1 and one of R₂ₐ to R_{2d} is a group represented by Formula 1-1; one of R₁ₐ to R_{1d} is a group represented by Formula 1-1 and one of R₃ₐ to R_{3c} is a group represented by Formula 1-1; one of R₂ₐ to R_{2d} is a group represented by Formula 1-1 and one of R₃ₐ to R_{3c} is a group represented by Formula 1-1;
(vi) two of R₁ₐ to R_{1d} may each be a group represented by Formula 1-1 and one of R₂ₐ to R_{2d} may each be a group represented by Formula 1-1; two of R₁ₐ to R_{1d} may each be a group represented by Formula 1-1 and one of R₃ₐ to R_{3c} may be a group represented by Formula 1-1; two of R₂ₐ to R_{2d} may each be a group represented by Formula 1-1 and one of R₁ₐ to R_{1d} may be a group represented by Formula 1-1; two of R₂ₐ to R_{2d} may each be a group represented by Formula 1-1 and one of R₃ₐ to R_{3c} may be a group represented by Formula 1-1; two of R₃ₐ to R_{3c} may each be a group represented by Formula 1-1 and one of R₁ₐ to R_{1d} may be a group represented by Formula 1-1; two of R₃ₐ to R_{3c} may each be a group represented by Formula 1-1 and one of R₂ₐ to R_{2d} may be a group represented by Formula 1-1; or one of R₁ₐ to R_{1d} may be a group represented by Formula 1-1, one of R₂ₐ to R_{2d} may be a group represented by Formula 1-1, and one of R₃ₐ to R_{3c} may be a group represented by Formula 1-1;
(vii) two of R₁ₐ to R_{1d} may each be a group represented by Formula 1-1 and two of R₂ₐ to R_{2d} may each be a group represented by Formula 1-1; two of R₁ₐ to R_{1d} may each be a group represented by Formula 1-1 and two of R₃ₐ to R_{3c} may each be a group represented by Formula 1-1; two of R₂ₐ to R_{2d} may each be a group represented by Formula 1-1 and two of R₃ₐ to R_{3c} may each be a group represented by Formula 1-1; two of R₁ₐ to R_{1d} may each be a group represented by Formula 1-1, one of R₂ₐ to R_{2d} may be a group represented by Formula 1-1, and one of R₃ₐ to R_{3c} may be a group represented by Formula 1-1; two of R₂ₐ to R_{2d} may each be a group represented by Formula 1-1, one of R₁ₐ to R_{1d} may be a group represented by Formula 1-1, and one of R₃ₐ to R_{3c} may be a group represented by Formula 1-1; two of R₃ₐ to R_{3c} may each be a group represented by Formula 1-1, one of R₁ₐ to R_{1d} may be a group represented by Formula 1-1, and one of R₂ₐ to R_{2d} may be a group represented by Formula 1-1; three of R₁ₐ to R_{1d} may each be a group represented by Formula 1-1 and one of R₂ₐ to R_{2d} may be a group represented by Formula 1-1; three of R₂ₐ to R_{2d} may each be a group represented by Formula 1-1 and one of R₁ₐ to R_{1d} may be a group represented by Formula 1-1; three of R₁ₐ to R_{1d} may each be a group represented by Formula 1-1 and one of R₃ₐ to R_{3c} may be a group represented by Formula 1-1; three of R₂ₐ to R_{2d} may each be a group represented by Formula 1-1 and one of R₃ₐ to R_{3c} may be a group represented by Formula 1-1; R₃ₐ to R_{3c} may each be a group represented by Formula 1-1 and one of R₁ₐ to R_{1d} may be a group represented by Formula 1-1; R₃ₐ to R_{3c} may each be a group represented by Formula 1-1 and one of R₂ₐ to R_{2d} may be a group represented by Formula 1-1;
(viii) R₁ₐ to R_{1d} may each be a group represented by Formula 1-1 and one of R₂ₐ to R_{2d} may be a group represented by Formula 1-1; R₁ₐ to R_{1d} may each be a group represented by Formula 1-1 and one of R₃ₐ to R_{3c} may be a group represented by Formula 1-1; three of R₁ₐ to R_{1d} may each be a group represented by Formula 1-1, one of R₂ₐ to R_{2d} may be a group represented by Formula 1-1, and one of R₃ₐ to R_{3c} may be a group represented by Formula 1-1; three of R₁ₐ to R_{1d} may each be a group represented by Formula 1-1 and two of R₂ₐ to R_{2d} may each be a group represented by Formula 1-1; three of R₁ₐ to R_{1d} may each be a group represented by Formula 1-1 and two of R₃ₐ to R_{3c} may each be a group represented by Formula 1-1; two of R₁ₐ to R_{1d} may each be a group represented by Formula 1-1 and three of R₂ₐ to R_{2d} may each be a group represented by Formula 1-1; two of R₁ₐ to R_{1d} may each be a group represented by Formula 1-1, two of R₂ₐ to R_{2d} may each be a group represented by Formula 1-1, and one of R₃ₐ to R_{3c} may be a group represented by Formula 1-1; two of R₁ₐ to R_{1d} may each be a group represented by Formula 1-1; one of R₂ₐ to R_{2d} may be a group represented by Formula 1-1, and two of R₃ₐ to R_{3c} may each be a group represented by Formula 1-1; two of R₁ₐ to R_{1d} may each be a group represented by Formula 1-1 and R₃ₐ to R_{3c} may each be a group represented by Formula 1-1; one of R₁ₐ to R_{1d} may be a group represented by Formula 1-1 and R₂ₐ to R_{2d} may each be a group represented by Formula 1-1; one of R₁ₐ to R_{1d} may be a group represented by Formula 1-1, three of R₂ₐ to R_{2d} may each be a group represented by Formula 1-1, and one of R₃ₐ to R_{3c} may be a group represented by Formula 1-1; one of R₁ₐ to R_{1d} may be a group represented by Formula 1-1, two of R₂ₐ to R_{2d} may each be a group represented by Formula 1-1, and two of R₃ₐ to R_{3c} may each be a group represented by Formula 1-1; one of R₁ₐ to R_{1d} may be a group represented by Formula 1-1, one of R₂ₐ to R_{2d} may be a group represented by Formula 1-1, and R₃ₐ to R_{3c} may each be a group represented by Formula 1-1; R₂ₐ to R_{2d} may each be a group represented by Formula 1-1 and one of R₃ₐ to R_{3c} may be a group represented by Formula 1-1; three of R₂ₐ to R_{2d} may each be a group represented by Formula 1-1 and two of R₃ₐ to R_{3c} may each be a group represented by Formula 1-1; two of R₂ₐ to R_{2d} may each be a group represented by Formula 1-1 and R₃ₐ to R_{3c} may each be a group represented by Formula 1-1; and
(ix) R₁ₐ to R_{1d} may each be a group represented by Formula 1-1 and two of R₂ₐ to R_{2d} may each be a group represented by Formula 1-1; R₁ₐ to R_{1d} may each be a group represented by Formula 1-1, one of R₂ₐ to R_{2d} may be a group represented by Formula 1-1, and one of R₃ₐ to R_{3c} may be a group represented by Formula 1-1; R₁ₐ to R_{1d} may each be a group represented by Formula 1-1 and two of R₃ₐ to R_{3c} may each be a group represented by Formula 1-1; three of R₁ₐ to R_{1d} may each be a group represented by Formula 1-1 and three of R₂ₐ to R_{2d} may each be a group represented by Formula 1-1; three of R₁ₐ to R_{1d} may each be a group represented by Formula 1-1, two of R₂ₐ to R_{2d} may each be a group represented by Formula 1-1, and one of R₃ₐ to R_{3c} may be a group represented by Formula 1-1; three of R₁ₐ to R_{1d} may each be a group represented by Formula 1-1, one of R₂ₐ to R_{2d} may be a group represented by Formula 1-1, and two of R₃ₐ to R_{3c} may each be a group represented by Formula 1-1; three of R₁ₐ to R_{1d} may each be a group represented by Formula 1-1 and R₃ₐ to R_{3c} may each be a group represented by Formula 1-1; two of R₁ₐ to R_{1d} may each be a group represented by Formula 1-1 and R₂ₐ to R_{2d} may each be a group represented by Formula 1-1; two of R₁ₐ to R_{1d} may each be a group represented by Formula 1-1, three of R₂ₐ to R_{2d} may each be a group represented by Formula 1-1, and one of R₃ₐ to R_{3c} may be a group represented by Formula 1-1; two of R₁ₐ to R_{1d} may each be a group represented by Formula 1-1, two of R₂ₐ to R_{2d} may each be a group represented by Formula 1-1, and two of R₃ₐ to R_{3c} may each be a group represented by Formula 1-1; two of R₁ₐ to R_{1d} may each be a group represented by Formula 1-1, one of R₂ₐ to R_{2d} may be a group represented by Formula 1-1, and R₃ₐ to R_{3c} may each be a group represented by Formula 1-1; one of R₁ₐ to R_{1d} may be a group represented by Formula 1-1, R₂ₐ to R_{2d} may each be a group represented by Formula 1-1, and one of R₃ₐ to R_{3c} may be a group represented by Formula 1-1; one of R₁ₐ to R_{1d} may be a group represented by Formula 1-1, three of R₂ₐ to R_{2d} may each be a group represented by Formula 1-1, and two of R₃ₐ to R_{3c} may each be a group represented by Formula 1-1; one of R₁ₐ to R_{1d} may be a group represented by Formula 1-1, two of R₂ₐ to R_{2d} may each be a group represented by Formula 1-1, and R₃ₐ to R_{3c} may each be a group represented by Formula 1-1; R₂ₐ to R_{2d} may each be a group represented by Formula 1-1 and two of R₃ₐ to R_{3c} may each be a group represented by Formula 1-1; three of R₂ₐ to R_{2d} may each be a group represented by Formula 1-1 and R₃ₐ to R_{3c} may each be a group represented by Formula 1-1.

For example, R₁ₐ, R_{1b}, R_{1c}, R_{1d}, R₂ₐ, R_{2b}, R_{2c}, R_{2d}, R₃ₐ, R_{3b}, and R_{3c} in Formula 2 may each independently be:
a group represented by Formula 1-1,
hydrogen, deuterium, —F, —Cl, —Br, —I, a hydroxyl group, a cyano group (CN), a nitro group, an amino group, a methyl group, an ethyl group, a propyl group, an isopropyl group, a butyl group, a sec-butyl group, an isobutyl group, a tert-butyl group, a methoxy group, an ethoxy group, a propoxy group, an isopropoxy group, a butoxy group, a sec-butoxy group, a tert-butoxy group, or an isobutoxy group;
a methyl group, an ethyl group, a propyl group, an isopropyl group, a butyl group, a sec-butyl group, an isobutyl group, a tert-butyl group, a methoxy group, an ethoxy group, a propoxy group, an isopropoxy group, a butoxy group, a sec-butoxy group, a tert-butoxy group, or an isobutoxy group, each substituted with at least one of deuterium, —F, —Cl, —Br, —I, a hydroxyl group, a cyano group (CN), a nitro group, an amino group, a phenyl group, a biphenyl group, a naphthyl group, a fluorenyl group, a phenanthrenyl group, an anthracenyl group, a fluoranthenyl group, a triphenylenyl group, a pyrenyl group, or a chrysenyl group;
a cyclopentyl group, a cyclohexyl group, a cycloheptyl group, a cyclopentenyl group, a cyclohexenyl group, a cycloheptenyl group, a phenyl group, a biphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyrdazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a phenanthrolinyl group, a benzimidazolyl group, a benzofuranyl group, a benzothiophenyl group, a benzoisothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, or a carbazolyl group; or a cyclopentyl group, a cyclohexyl group, a cycloheptyl group, a cyclopentenyl
group, a cyclohexenyl group, a cycloheptenyl group, a phenyl group, a biphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a phenanthrolinyl group, a benzimidazolyl group, a benzofuranyl group, a benzothiophenyl group, a benzoisothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, or a carbazolyl group, each substituted with at least one of deuterium, —F, —Cl, —Br, —I, a hydroxyl group, a cyano group, a nitro group, an amino group, a methyl group, an ethyl group, a propyl group, an isopropyl group, a butyl group, a sec-butyl group, an isobutyl group, a tert-butyl group, a methoxy group, an ethoxy group, a propoxy group, an isopropoxy group, a butoxy group, a sec-butoxy group, tert-butoxy group, isobutoxy group, a C₇-C₆₀ aryl alkyl group, a cyclopentyl group, a cyclohexyl group, a cycloheptyl group, a cyclopentenyl group, a cyclohexenyl group, a cycloheptenyl group, a phenyl group, a biphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a phenanthrolinyl group, a benzimidazolyl group, a benzofuranyl group, a benzothiophenyl group, a benzoisothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, or a carbazolyl group, but embodiments of the present disclosure are not limited thereto.

For example, from among R₁ₐ, R_{1b}, R_{1c}, R_{1d}, R₂ₐ, R_{2b}, R_{2c}, R_{2d}, R₃ₐ, R_{3b}, and R_{3c}, a group that is not the group represented by Formula 1-1 may be hydrogen.

In one or more embodiments, the polycyclic compound may be represented by Formula 2A below:

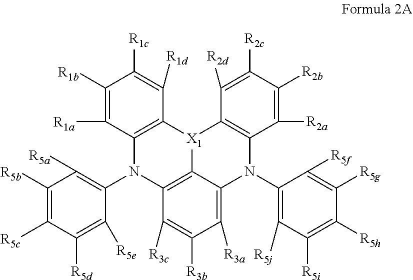

wherein, in Formula 2A,
X₁ is the same as described above,
R₁ₐ to R_{1d} are each the same as described in connection with R₁ as described above, R₂ₐ to R_{2d} are each the same as described in connection with R₂ as described above, and R₃ₐ to R_{3c} are each the same as described in connection with R₃ as described above, and R₅ₐ to R₅ⱼ are each the same as described in connection with R₅ as described above, and
(i) one of R₁ₐ to R_{1d} is a group represented by Formula 1-1; one of R₂ₐ to R_{2d} is a group represented by Formula 1-1; one of R₃ₐ to R_{3c} is a group represented by Formula 1-1; one of R₅ₐ to R₅ₑ is a group represented by Formula 1-1; or one of R_{5f} to R₅ⱼ is a group represented by Formula 1-1;
(ii) two of R₁ₐ to R_{1d} are each a group represented by Formula 1-1; two of R₂ₐ to R_{2d} are each a group represented by Formula 1-1; two of R₃ₐ to R_{3c} are each a group represented by Formula 1-1; two of R₅ₐ to R₅ₑ are each a group represented by Formula 1-1; or two of R₅ₐ to R₅ₑ are each a group represented by Formula 1-1;
(iii) three of R₁ₐ to R_{1d} are each a group represented by Formula 1-1; three of R₂ₐ to R_{2d} are each a group represented by Formula 1-1; each of R₃ₐ to R_{3c} is a group represented by Formula 1-1; three of R₅ₐ to R₅ₑ are each a group represented by Formula 1-1; or three of R_{5f} to R₅ⱼ are each a group represented by Formula 1-1;
(iv) each of R₁ₐ to R_{1d} is a group represented by Formula 1-1; each of R₂ₐ to R_{2d} is a group represented by Formula 1-1; four of R₅ₐ to R₅ₑ are each a group represented by Formula 1-1; or four of R_{5f} to R₅ⱼ are each a group represented by Formula 1-1;
(v) each of R₅ₑ to R₃ₐ is a group represented by Formula 1-1 or each of R_{5f} to R₅ⱼ is a group represented by Formula 1-1;
(vi) one of R₁ₐ to R_{1d} is a group represented by Formula 1-1 and one of R₂ₐ to R_{2d} is a group represented by Formula 1-1; one of R₁ₐ to R_{1d} is a group represented by Formula 1-1 and one of R₃ₐ to R_{3c} is a group represented by Formula 1-1; one of R₁ₐ to R_{1d} is a group represented by Formula 1-1 and one of R₅ₐ to R₅ₑ is a group represented by Formula 1-1; one of R₁ₐ to R_{1d} is a group represented by Formula 1-1 and one of R_{5f} to R₅ⱼ is a group represented by Formula 1-1; one of R₂ₐ to R_{2d} is a group represented by Formula 1-1 and one of R₃ₐ to R_{3c} is a group represented by Formula 1-1; one of R₂ₐ to R_{2d} is a group represented by Formula 1-1 and one of R₅ₐ to R₅ₑ is a group represented by Formula 1-1; one of R₂ₐ to R_{2d} is a group represented by Formula 1-1 and one of R_{5f} to R₅ⱼ is a group represented by Formula 1-1; one of R₃ₐ to R_{3c} is a group represented by Formula 1-1 and one of R₅ₐ to R₅ₑ is a group represented by Formula 1-1; one of R₃ₐ to R_{3c} is a group represented by Formula 1-1 and one of R_{5f} to Rⱼ is a group represented by Formula 1-1; one of R₅ₐ to R₅ₑ is a group represented by Formula 1-1 and one of R_{5f} to R₅ⱼ is a group represented by Formula 1-1;
(vii) two of R₁ₐ to R_{1d} are each a group represented by Formula 1-1 and one of R₂ₐ to R_{2d} is a group represented by Formula 1-1; two of R₁ₐ to R_{1d} are each a group represented by Formula 1-1 and one of R₃ₐ to R_{3c} is a group represented by Formula 1-1; two of R₁ₐ to R_{1d} are each a group represented by Formula 1-1 and one of R₃ₐ to R_{3c} is a group represented by Formula 1-1; two of R₁ₐ to R_{1d} are each a group represented by Formula 1-1 and one of R_{5f} to R₅ⱼ is a group represented by Formula 1-1; two of R₂ₐ to R_{2d} are each a group represented by Formula 1-1 and one of R₁ₐ to R_{1d} is a group represented by Formula 1-1; two of R₂ₐ to R_{2d} are each a group represented by Formula 1-1 and one of R₃ₐ to R_{3c} is a group represented by Formula 1-1; two of R₂ₐ to R_{2d} are each a group represented by Formula 1-1 and one of R₅ₐ to Rₑ is a group represented by Formula 1-1; two of R₂ₐ to R_{2d} are each a group represented by Formula 1-1 and one of R_{5f} to R₅ⱼ is a group represented by Formula 1-1; two of R₃ₐ to R_{3c} are each a group represented by Formula 1-1 and one of R₁ₐ to R_{1d} is a group represented by Formula 1-1; two of R₃ₐ to R_{3c} are each a group represented by Formula 1-1 and one of R₂ₐ to R_{2d} is a group represented by Formula 1-1; two of R₃ₐ to R_{3c} are each a group represented by Formula 1-1 and one of R₅ₐ to R₅ₑ is a group represented by Formula 1-1; two of R₃ₐ to R_{3c} are each a group represented by Formula 1-1 and one of R_{5f} to R₅ⱼ is a group represented by Formula 1-1; two of R₅ₐ to R₅ₑ are each a group represented by Formula 1-1 and one of R₁ₐ to R_{1d} is a group represented by Formula 1-1; two of R₅ₐ to R₅ₑ are each a group represented by Formula 1-1 and one of R₂ₐ to R_{2d} is a group represented by Formula 1-1; two of R₅ₐ to R₅ₑ are each a group represented by Formula 1-1 and one of R₃ₐ to R_{3c} is a group represented by Formula 1-1; two of R₅ₐ to R₅ₑ are each a group represented by Formula 1-1 and one of R_{5f} to R₅ⱼ is a group represented by Formula 1-1; two of R_{5f} to R₅ⱼ are each a group represented by Formula 1-1 and one of R₁ₐ to R_{1d} is a group represented by Formula 1-1; two of R_{5f} to R₅ⱼ are each a group represented by Formula 1-1 and one of R₂ₐ to R_{2d} is a group represented by Formula 1-1; two of R_{5f} to R₅ⱼ are each a group represented by Formula 1-1 and one of R₃ₐ to R_{3c} is a group represented by Formula 1-1; two of R_{5f} to Rⱼ are each a group represented by Formula 1-1 and one of R₅ₐ to R₅ₑ is a group represented by Formula 1-1, one of R₁ₐ to R_{1d} is a group represented by Formula 1-1, one of R₂ₐ to R_{2d} is a group represented by Formula 1-1, and one of R₃ₐ to R_{3c} is a group represented by Formula 1-1; one of R₁ₐ to R_{1d} is a group represented by Formula 1-1, one of R₂ₐ to R_{2d} is a group represented by Formula 1-1, and one of R₅ₐ to R₅ₑ is a group represented by Formula 1-1; one of R₁ₐ to R_{1d} is a group represented by Formula 1-1, one of R₂ₐ to R_{2d} is a group represented by Formula 1-1, and one of R_{5f} to R₅ⱼ is a group represented by Formula 1-1; one of R₁ₐ to R_{1d} is a group represented by Formula 1-1, one of R₃ₐ to R_{3c} is a group represented by Formula 1-1, and one of R₅ₐ to R₅ₑ is a group represented by Formula 1-1; one of R₁ₐ to R_{1d} is a group represented by Formula 1-1, one of R₃ₐ to R_{3c} is a group represented by Formula 1-1, and one of R_{5f} to R₅ⱼ is a group represented by Formula 1-1; one of R₁ₐ to R_{1d} is a group represented by Formula 1-1, one of R₅ₐ to R₅ₑ is a group represented by Formula 1-1, and one of R_{5f} to R₅ⱼ is a group represented by Formula 1-1; one of R₂ₐ to R_{2d} is a group represented by Formula 1-1, one of R₃ₐ to R_{3c} is a group represented by Formula 1-1, and one of R₅ₐ to R₅ₑ is a group represented by Formula 1-1; one of R₂ₐ to R_{2d} is a group represented by Formula 1-1, one of R₃ₐ to R_{3c} is a group represented by Formula 1-1, and one of R_{5f} to R₅ⱼ is a group represented by Formula 1-1; one of R₂ₐ to R_{2d} is a group represented by Formula 1-1, one of R₅ₐ to R₅ₑ is a group represented by Formula 1-1, and one of R_{5f} to R₅ⱼ is a group represented by Formula 1-1; or one of R₃ₐ to R_{3c} is a group represented by Formula 1-1, one of R₅ₐ to R₅ₑ is a group represented by Formula 1-1, and one of R_{5f} to R₅ⱼ is a group represented by Formula 1-1;
(viii) two of R₁ₐ to R_{1d} are each a group represented by Formula 1-1 and two of R₂ₐ to R_{2d} are each a group represented by Formula 1-1; two of R₁ₐ to R_{1d} are each a group represented by Formula 1-1 and two of R₃ₐ to R_{3c} are each a group represented by Formula 1-1; two of R₁ₐ to R_{1d} are each a group represented by Formula 1-1 and two of R₅ₐ to R₅ₑ are each a group represented by Formula 1-1; two of R₁ₐ to R_{1d} are each a group represented by Formula 1-1 and two of R_{5f} to R₅ⱼ are each a group represented by Formula 1-1; two of R₂ₐ to R_{2d} are each a group represented by Formula 1-1 and two of R₃ₐ to R_{3c} are each a group represented by Formula 1-1; two of R₂ₐ to R_{2d} are each a group represented by Formula 1-1 and two of R₅ₐ to R₅ₑ are each a group represented by Formula 1-1; two of R₂ₐ to R_{2d} are each a group represented by Formula 1-1 and two of R_{5f} to R₅ⱼ are each a group represented by Formula 1-1; two of R₃ₐ to R_{3c} are each a group represented by Formula 1-1 and two of R₅ₐ to R₅ₑ are each a group represented by Formula 1-1; two of R₃ₐ to R_{3c} are each a group represented by Formula 1-1 and two of R_{5f} to R₅ⱼ are each a group represented by Formula 1-1; two of R₅ₐ to R₅ₑ are each a group represented by Formula 1-1 and two of R_{5f} to R₅ⱼ are each a group represented by Formula 1-1; two of R₁ₐ to R_{1d} are each a group represented by Formula 1-1, one of R₂ₐ to R_{2d} is a group represented by Formula 1-1, and one of R₃ₐ to R_{3c} is a group represented by Formula 1-1; two of R₁ₐ to R_{1d} are each a group represented by Formula 1-1, one of R₂ₐ to R_{2d} is a group represented by Formula 1-1, and one of R₅ₐ to R₅ₑ is a group represented by Formula 1-1; two of R₁ₐ to R_{1d} are each a group represented by Formula 1-1, one of R₂ₐ to R_{2d} is a group represented by Formula 1-1, and one of R_{5f} to R₅ⱼ is a group represented by Formula 1-1; two of R₁ₐ to R_{1d} are each a group represented by Formula 1-1, one of R₃ₐ to R_{3c} is a group represented by Formula 1-1, and one of R₅ₐ to R₅ₑ is a group represented by Formula 1-1; two of R₁ₐ to R_{1d} are each a group represented by Formula 1-1, one of R₃ₐ to R_{3c} is a group represented by Formula 1-1, and one of R_{5f} to R₅ⱼ is a group represented by Formula 1-1; two of R₁ₐ to R_{1d} are each a group represented by Formula 1-1, one of R₅ₐ to R₅ₑ is a group represented by Formula 1-1, and one of R_{5f} to R₅ⱼ is a group represented by Formula 1-1; two of R₂ₐ to R_{2d} are each a group represented by Formula 1-1, one of R₁ₐ to R_{1d} is a group represented by Formula 1-1, and one of R₃ₐ to R_{3c} is a group represented by Formula 1-1; two of R₂ₐ to R_{2d} are each a group represented by Formula 1-1, one of R₁ₐ to R_{1d} is a group represented by Formula 1-1, and one of R₅ₐ to R₅ₑ is a group represented by Formula 1-1; two of R₂ₐ to R_{2d} are each a group represented by Formula 1-1, one of R₁ₐ to R_{1d} is a group represented by Formula 1-1, and one of R_{5f} to R₅ⱼ is a group represented by Formula 1-1; two of R₂ₐ to R_{2d} are each a group represented by Formula 1-1, one of R₃ₐ to R_{3c} is a group represented by Formula 1-1, and one of R₅ₐ to R₅ₑ is a group represented by Formula 1-1; two of R₂ₐ to R_{2d} are each a group represented by Formula 1-1, one of R₃ₐ to R_{3c} is a group represented by Formula 1-1, and one of R_{5f} to R₅ⱼ is a group represented by Formula 1-1; two of R₂ₐ to R_{2d} are each a group represented by Formula 1-1, one of R₅ₐ to R₅ₑ is a group represented by Formula 1-1, and one of R_{5f} to R₅ⱼ is a group represented by Formula 1-1; two of R₃ₐ to R_{3c} are each a group represented by Formula 1-1, one of R₁ₐ to R_{1d} is a group represented by Formula 1-1, and one of R₂ₐ to R_{2d} is a group represented by Formula 1-1; two of R₃ₐ to R_{3c} are each a group represented by Formula 1-1, one of R₁ₐ to R_{1d} is a group represented by Formula 1-1, and one of R₅ₐ to R₅ₑ is a group represented by Formula 1-1; two of R₃ₐ to R_{3c} are each a group represented by Formula 1-1, one of R₁ₐ to R_{1d} is a group represented by Formula 1-1, and one of R_{5f} to R₅ⱼ is a group represented by Formula 1-1; two of R₃ₐ to R_{3c} are each a group represented by Formula 1-1, one of R₂ₐ to R_{2d} is a group represented by Formula 1-1, and one of R₅ₐ to R₅ₑ is a group represented by Formula 1-1; two of R₃ₐ to R_{3c} are each a group represented by Formula 1-1, one of R₂ₐ to R_{2d} is a group represented by Formula 1-1, and one of R_{5f} to R₅ⱼ is a group represented by Formula 1-1; two of R₃ₐ to R_{3c} are each a group represented by Formula 1-1, one of R₅ₐ to R₅ₑ is a group represented by Formula 1-1, and one of R_{5f} to Rⱼ is a group represented by Formula 1-1; two of R₅ₐ to R₅ₑ are each a group represented by Formula 1-1, one of R₁ₐ to R_{1d} is a group represented by Formula 1-1, and one of R₂ₐ to R_{2d} is a group represented by Formula 1-1; two of R₅ₐ to R₅ₑ are each a group represented by Formula 1-1, one of R₁ₐ to R_{1d} is a group represented by Formula 1-1, and one of R₃ₐ to R_{3c} is a group represented by Formula 1-1; two of R₅ₐ to R₅ₑ are each a group represented by Formula 1-1, one of R₁ₐ to R_{1d} is a group represented by Formula 1-1, and one of R_{5f} to R₅ⱼ is a group represented by Formula 1-1; two of R₅ₐ to R₅ₑ are each a group represented by Formula 1-1, one of R₂ₐ to R_{2d} is a group represented by Formula 1-1, and one of R₃ₐ to R_{3c} is a group represented by Formula 1-1; two of R₅ₐ to R₅ₑ are each a group represented by Formula 1-1, one of R₂ₐ to R_{2d} is a group represented by Formula 1-1, and one of R_{5f} to R₅ⱼ is a group represented by Formula 1-1; two of R₅ₐ to R₅ₑ are each a group represented by Formula 1-1, one of R₃ₐ to R_{3c} is a group represented by Formula 1-1, and one of R_{5f} to R₅ⱼ is a group represented by Formula 1-1; two of R_{5f} to R₅ⱼ are each a group represented by Formula 1-1, one of R₁ₐ to R_{1d} is a group represented by Formula 1-1, and one of R₂ₐ to R_{2d} is a group represented by Formula 1-1; two of R_{5f} to R₅ⱼ are each a group represented by Formula 1-1, one of R₁ₐ to R_{1d} is a group represented by Formula 1-1, and one of R₃ₐ to R_{3c} is a group represented by Formula 1-1; two of R_{5f} to Rⱼ are each a group represented by Formula 1-1, one of R₁ₐ to R_{1d} is a group represented by Formula 1-1, and one of R₅ₐ to R₅ₑ is a group represented by Formula 1-1; two of R_{5f} to R₅ⱼ are each a group represented by Formula 1-1, one of R₂ₐ to R_{2d} is a group represented by Formula 1-1, and one of R₃ₐ to R_{3c} is a group represented by Formula 1-1; two of R_{5f} to R₅ⱼ are each a group represented by Formula 1-1, one of R₂ₐ to R_{2d} is a group represented by Formula 1-1, and one of R₅ₐ to R₅ₑ is a group represented by Formula 1-1; two of R_{5f} to R₅ⱼ are each a group represented by Formula 1-1, one of R₃ₐ to R_{3c} is a group represented by Formula 1-1, and one of R₅ₐ to R₅ₑ is a group represented by Formula 1-1; three of R₁ₐ to R_{1d} are each a group represented by Formula 1-1, and one of R₂ₐ to R_{2d} is a group represented by Formula 1-1; three of R₁ₐ to R_{1d} are each a group represented by Formula 1-1, and one of R₅ₐ to R₅ₑ is a group represented by Formula 1-1; three of R₁ₐ to R_{1d} are each a group represented by Formula 1-1, and one of R_{5f} to R₅ⱼ is a group represented by Formula 1-1; three of R₂ₐ to R_{2d} are each a group represented by Formula 1-1 and one of R₁ₐ to R_{1d} is a group represented by Formula 1-1; three of R₂ₐ to R_{2d} are each a group represented by Formula 1-1 and one of R₅ₐ to R₅ₑ is a group represented by Formula 1-1; three of R₂ₐ to R_{2d} are each a group represented by Formula 1-1 and one of R_{5f} to Rⱼ is a group represented by Formula 1-1; three of R₁ₐ to R_{1d} are each a group represented by Formula 1-1 and one of R₃ₐ to R_{3c} is a group represented by Formula 1-1; three of R₂ₐ to R_{2d} are each a group represented by Formula 1-1 and one of R₃ₐ to R_{3c} is a group represented by Formula 1-1; R₃ₐ to R_{3c} are each a group represented by Formula 1-1 and one of R₁ₐ to R_{1d} is a group represented by Formula 1-1; R₃ₐ to R_{3c} are each a group represented by Formula 1-1 and one of R₅ₐ to R₅ₑ is a group represented by Formula 1-1; R₃ₐ to R_{3c} are each a group represented by Formula 1-1 and one of R_{5f} to R₅ⱼ is a group represented by Formula 1-1; R₃ₐ to R_{3c} are each a group represented by Formula 1-1 and one of R₂ₐ to R_{2d} is a group represented by Formula 1-1, three of R₅ₐ to R_{5d} are each a group represented by Formula 1-1, and one of R₁ₐ to R_{1d} is a group represented by Formula 1-1; three of R₅ₐ to R_{5d} are each a group represented by Formula 1-1, and one of R₂ₐ to R_{2d} is a group represented by Formula 1-1; three of R₅ₐ to R_{5d} are each a group represented by Formula 1-1, and one of R₃ₐ to R_{3c} is a group represented by Formula 1-1; or three of R₃ₐ to R_{3c} are each a group represented by Formula 1-1, and one of R_{5f} to Rⱼ is a group represented by Formula 1-1;
(ix) R₁ₐ to R_{1d} are each a group represented by Formula 1-1 and one of R₂ₐ to R_{2d} is a group represented by Formula 1-1; R₁ₐ to R_{1d} are each a group represented by Formula 1-1 and one of R₃ₐ to R_{3c} is a group represented by Formula 1-1; R₁ₐ to R_{1d} are each a group represented by Formula 1-1 and one of R₅ₐ to R₅ₑ is a group represented by Formula 1-1; R₁ₐ to R_{1d} are each a group represented by Formula 1-1 and one of R_{5f} to R_{fj} is a group represented by Formula 1-1; three of R₁ₐ to R_{1d} are each a group represented by Formula 1-1, one of R₂ₐ to R_{2d} is a group represented by Formula 1-1, and one of R₃ₐ to R_{3c} is a group represented by Formula 1-1; three of R₁ₐ to R_{1d} are each a group represented by Formula 1-1, one of R₂ₐ to R_{2d} is a group represented by Formula 1-1, and one of R₅ₐ to R₅ₑ is a group represented by Formula 1-1; three of R₁ₐ to R_{1d} are each a group represented by Formula 1-1, one of R₂ₐ to R_{2d} is a group represented by Formula 1-1, and one of R_{5f} to Rⱼ is a group represented by Formula 1-1; three of R₁ₐ to R_{1d} are each a group represented by Formula 1-1, one of R₃ₐ to R_{3c} is a group represented by Formula 1-1, and one of R₅ₐ to R₅ₑ is a group represented by Formula 1-1; three of R₁ₐ to R_{1d} are each a group represented by Formula 1-1, one of R₃ₐ to R_{3c} is a group represented by Formula 1-1, and one of R₅ₐ to R₅ₑ is a group represented by Formula 1-1; three of R₁ₐ to R_{1d} are each a group represented by Formula 1-1, one of R₅ₐ to R₅ₑ is a group represented by Formula 1-1, and one of R_{5f} to R₅ⱼ is a group represented by Formula 1-1; three of R₁ₐ to R_{1d} are each a group represented by Formula 1-1 and two of R₂ₐ to R_{2d} are each a group represented by Formula 1-1; three of R₁ₐ to R_{1d} are each a group represented by Formula 1-1 and two of R₃ₐ to R_{3c} are each a group represented by Formula 1-1; three of R₁ₐ to R_{1d} are each a group represented by Formula 1-1 and two of R₅ₐ to R₅ₑ are each a group represented by Formula 1-1; three of R₁ₐ to R_{1d} are each a group represented by Formula 1-1 and two of R_{5f} to R₅ⱼ are each a group represented by Formula 1-1; two of R₁ₐ to R_{1d} are each a group represented by Formula 1-1 and three of R₂ₐ to R_{2d} are each a group represented by Formula 1-1; two of R₁ₐ to R_{1d} are each a group represented by Formula 1-1, two of R₂ₐ to R_{2d} are each a group represented by Formula 1-1, and one of R₃ₐ to R_{3c} is a group represented by Formula 1-1; two of R₁ₐ to R_{1d} are each a group represented by Formula 1-1, two of R₂ₐ to R_{2d} are each a group represented by Formula 1-1, and one of R₅ₐ to R₅ₑ is a group represented by Formula 1-1; two of R₁ₐ to R_{1d} are each a group represented by Formula 1-1, two of R₂ₐ to R_{2d} are each a group represented by Formula 1-1, and one of R_{5f} to Rⱼ is a group represented by Formula 1-1; two of R₁ₐ to R_{1d} are each a group represented by Formula 1-1, one of R₂ₐ to R_{2d} is a group represented by Formula 1-1, and two of R₃ₐ to R_{3c} are each a group represented by Formula 1-1; two of R₁ₐ to R_{1d} are each a group represented by Formula 1-1, one of R₂ₐ to R_{2d} is a group represented by Formula 1-1, and two of R₅ₐ to R₅ₑ are each a group represented by Formula 1-1; two of R₁ₐ to R_{1d} are each a group represented by Formula 1-1, one of R₂ₐ to R_{2d} is a group represented by Formula 1-1, and two of R_{5f} to R₅ⱼ are each a group represented by Formula 1-1; two of R₁ₐ to R_{1d} are each a group represented by Formula 1-1 and R₃ₐ to R_{3c} are each a group represented by Formula 1-1; two of R₁ₐ to R_{1d} are each a group represented by Formula 1-1 and three of R₅ₐ to R₅ₑ are each a group represented by Formula 1-1; two of R₁ₐ to R_{1d} are each a group represented by Formula 1-1 and three of R_{5f} to R₅ⱼ are each a group represented by Formula 1-1; one of R₁ₐ to R_{1d} is a group represented by Formula 1-1 and R₂ₐ to R_{2d} are each a group represented by Formula 1-1; one of R₁ₐ to R_{1d} is a group represented by Formula 1-1 and four of R₅ₐ to R₅ₑ are each a group represented by Formula 1-1; one of R₁ₐ to R_{1d} is a group represented by Formula 1-1 and four of R_{5f} to R₅ⱼ are each a group represented by Formula 1-1; one of R₁ₐ to R_{1d} is a group represented by Formula 1-1, three of R₂ₐ to R_{2d} are each a group represented by Formula 1-1, and one of R₃ₐ to R_{3c} is a group represented by Formula 1-1; one of R₁ₐ to R_{1d} is a group represented by Formula 1-1, three of R₂ₐ to R_{2d} are each a group represented by Formula 1-1, and one of R₅ₐ to R₅ₑ is a group represented by Formula 1-1; one of R₁ₐ to R_{1d} is a group represented by Formula 1-1, three of R₂ₐ to R_{2d} are each a group represented by Formula 1-1, and one of R_{5f} to Rⱼ is a group represented by Formula 1-1; one of R₁ₐ to R_{1d} is a group represented by Formula 1-1, two of R₂ₐ to R_{2d} are each a group represented by Formula 1-1, and two of R₃ₐ to R_{3c} are each a group represented by Formula 1-1; one of R₁ₐ to R_{1d} is a group represented by Formula 1-1, two of R₂ₐ to R_{2d} are each a group represented by Formula 1-1, and two of R₅ₐ to R₅ₑ are each a group represented by Formula 1-1; one of R₁ₐ to R_{1d} is a group represented by Formula 1-1, two of R₂ₐ to R_{2d} are each a group represented by Formula 1-1, and two of R_{5f} to R₅ⱼ are each a group represented by Formula 1-1; one of R₁ₐ to R_{1d} is a group represented by Formula 1-1, one of R₂ₐ to R_{2d} is a group represented by Formula 1-1, and R₃ₐ to R_{3c} are each a group represented by Formula 1-1; one of R₁ₐ to R_{1d} is a group represented by Formula 1-1, one of R₂ₐ to R_{2d} is a group represented by Formula 1-1, and three of R₅ₐ to R₅ₑ are each a group represented by Formula 1-1; one of R₁ₐ to R_{1d} is a group represented by Formula 1-1, one of R₂ₐ to R_{2d} is a group represented by Formula 1-1, and three of R_{5f} to R₅ⱼ are each a group represented by Formula 1-1; R₂ₐ to R_{2d} are each a group represented by Formula 1-1 and one of R₃ₐ to R_{3c} is a group represented by Formula 1-1; R₂ₐ to R_{2d} are each a group represented by Formula 1-1 and one of R₅ₐ to R₅ₑ is a group represented by Formula 1-1; R₂ₐ to R_{2d} are each a group represented by Formula 1-1 and one of R_{5f} to R₅ⱼ is a group represented by Formula 1-1; three of R₂ₐ to R_{2d} are each a group represented by Formula 1-1, and two of R₃ₐ to R_{3c} are each a group represented by Formula 1-1; three of R₂ₐ to R_{2d} are each a group represented by Formula 1-1, one of R₃ₐ to R_{3c} is a group represented by Formula 1-1, and one of R₅ₐ to R₅ₑ is a group represented by Formula 1-1; three of R₂ₐ to R_{2d} are each a group represented by Formula 1-1, one of R₃ₐ to R_{3c} is a group represented by Formula 1-1, and one of R_{5f} to Rⱼ is a group represented by Formula 1-1; three of R₂ₐ to R_{2d} are each a group represented by Formula 1-1, one of R₅ₐ to R₅ₑ is a group represented by Formula 1-1, and one of R_{5f} to Rⱼ is a group represented by Formula 1-1; three of R₂ₐ to R_{2d} are each a group represented by Formula 1-1, and two of R₅ₐ to R₅ₑ are each a group represented by Formula 1-1; three of R₂ₐ to R_{2d} are each a group represented by Formula 1-1, and two of R_{5f} to R₅ⱼ are each a group represented by Formula 1-1; two of R₂ₐ to R_{2d} are each a group represented by Formula 1-1 and R₃ₐ to R_{3c} are each a group represented by Formula 1-1; two of R₂ₐ to R_{2d} are each a group represented by Formula 1-1, two of R₃ₐ to R_{3c} are each a group represented by Formula 1-1 and one of R₅ₐ to R₅ₑ is a group represented by Formula 1-1; two of R₂ₐ to R_{2d} are each a group represented by Formula 1-1, two of R₃ₐ to R_{3c} are each a group represented by Formula 1-1 and one of R_{5f} to R₅ⱼ is a group represented by Formula 1-1; two of R₂ₐ to R_{2d} are each a group represented by Formula 1-1, one of R₃ₐ to R_{3c} is a group represented by Formula 1-1 and two of R₅ₐ to R₅ₑ are each a group represented by Formula 1-1; two of R₂ₐ to R_{2d} are each a group represented by Formula 1-1, one of R₃ₐ to R_{3c} is a group represented by Formula 1-1 and two of R₅ₐ to R₅ₑ are each a group represented by Formula 1-1; two of R₂ₐ to R_{2d} are each a group represented by Formula 1-1, one of R₃ₐ to R_{3c} is a group represented by Formula 1-1, one of R₅ₐ to R₅ₑ is a group represented by Formula 1-1 and one of R_{5f} to R₅ⱼ is a group represented by Formula 1-1; two of R₂ₐ to R_{2d} are each a group represented by Formula 1-1 and three of R₅ₐ to R₅ₑ are each a group represented by Formula 1-1; two of R₂ₐ to R_{2d} are each a group represented by Formula 1-1, two of R₅ₐ to R₅ₑ are each a group represented by Formula 1-1 and one of R_{5f} to R₅ⱼ is a group represented by Formula 1-1; two of R₂ₐ to R_{2d} are each a group represented by Formula 1-1, one of R₅ₐ to R₅ₑ is a group represented by Formula 1-1 and two of R_{5f} to R₅ⱼ are each a group represented by Formula 1-1; two of R₂ₐ to R_{2d} are each a group represented by Formula 1-1 and three of R_{5f} to R₅ⱼ are each a group represented by Formula 1-1; one of R₂ₐ to R_{2d} is a group represented by Formula 1-1, three of R₃ₐ to R_{3c} are each a group represented by Formula 1-1 and one of R₅ₐ to R₅ₑ is a group represented by Formula 1-1; one of R₂ₐ to R_{2d} is a group represented by Formula 1-1, three of R₃ₐ to R_{3c} are each a group represented by Formula 1-1 and one of R_{5f} to R₅ⱼ are each a group represented by Formula 1-1; one of R₂ₐ to R_{2d} is a group represented by Formula 1-1, two of R₃ₐ to R_{3c} are each a group represented by Formula 1-1 and two of R₅ₐ to R₅ₑ are each a group represented by Formula 1-1; one of R₂ₐ to R_{2d} is a group represented by Formula 1-1, two of R₃ₐ to R_{3c} are each a group represented by Formula 1-1 and two of R_{5f} to R₅ⱼ are each a group represented by Formula 1-1; one of R₂ₐ to R_{2d} is a group represented by Formula 1-1, one of R₃ₐ to R_{3c} is a group represented by Formula 1-1 and three of R₅ₐ to R₅ₑ are each a group represented by Formula 1-1; one of R₂ₐ to R_{2d} is a group represented by Formula 1-1, one of R₃ₐ to R_{3c} is a group represented by Formula 1-1 and three of R_{5f} to R₅ⱼ are each a group represented by Formula 1-1; one of R₂ₐ to R_{2d} is a group represented by Formula 1-1 and four of R₅ₐ to R₅ₑ are each a group represented by Formula 1-1; one of R₂ₐ to R_{2d} is a group represented by Formula 1-1 and four of R_{5f} to R₅ⱼ are each a group represented by Formula 1-1; one of R₂ₐ to R_{2d} is a group represented by Formula 1-1, three of R₅ₐ to R₅ₑ are each a group represented by Formula 1-1 and one of R_{5f} to R₅ⱼ is a group represented by Formula 1-1; one of R₂ₐ to R_{2d} is a group represented by Formula 1-1, two of R₅ₐ to R₅ₑ are each a group represented by Formula 1-1 and two of R_{5f} to R₅ⱼ are each a group represented by Formula 1-1; one of R₂ₐ to R_{2d} is a group represented by Formula 1-1, one of R₅ₐ to R₅ₑ is a group represented by Formula 1-1 and three of R_{5f} to R₅ⱼ are each a group represented by Formula 1-1; R₃ₐ to R_{3c} are each a group represented by Formula 1-1 and two of R₅ₐ to R₅ₑ are each a group represented by Formula 1-1; R₃ₐ to R_{3c} are each a group represented by Formula 1-1 and two of R_{5f} to R₅ⱼ are each a group represented by Formula 1-1; R₅ₐ to R₅ₑ are each a group represented by Formula 1-1, one of R₅ₐ to R₅ₑ is a group represented by Formula 1-1 and one of R_{5f} to R₅ⱼ is a group represented by Formula 1-1; two of R₃ₐ to R_{3c} are each a group represented by Formula 1-1 and three of R₅ₐ to R₅ₑ are each a group represented by Formula 1-1; two of R₃ₐ to R_{3c} are each a group represented by Formula 1-1 and three of R_{5f} to R₅ⱼ are each a group represented by Formula 1-1; two of R₃ₐ to R_{3c} are each a group represented by Formula 1-1, two of R₅ₐ to R₅ₑ are each a group represented by Formula 1-1, one of R_{5f} to R₅ⱼ is a group represented by Formula 1-1; two of R₃ₐ to R_{3c} are each a group represented by Formula 1-1, one of R₅ₐ to R₅ₑ is a group represented by Formula 1-1, two of R_{5f} to R₅ⱼ are each a group represented by Formula 1-1; one of R₃ₐ to R_{3c} is a group represented by Formula 1-1, four of R₅ₐ to R₅ₑ are each a group represented by Formula 1-1; one of R₃ₐ to R_{3c} is a group represented by Formula 1-1, four of R_{5f} to R₅ⱼ are each a group represented by Formula 1-1; one of R₃ₐ to R_{3c} is a group represented by Formula 1-1, three of R₅ₐ to R₅ₑ are each a group represented by Formula 1-1 and one of R_{5f} to R₅ⱼ is a group represented by Formula 1-1; one of R₃ₐ to R_{3c} is a group represented by Formula 1-1, two of R₅ₐ to R₅ₑ are each a group represented by Formula 1-1 and two of R_{5f} to R₅ⱼ are each a group represented by Formula 1-1; one of R₃ₐ to R_{3c} is a group represented by Formula 1-1, one of R₅ₐ to R₅ₑ is a group represented by Formula 1-1 and three of R_{5f} to R₅ⱼ are each a group represented by Formula 1-1; R₅ₐ to R₅ₑ are each a group represented by Formula 1-1; R_{5f} to R₅ⱼ are each a group represented by Formula 1-1; four of R₅ₐ to R₅ₑ are each a group represented by Formula 1-1 and one of R_{5f} to R₅ⱼ is a group represented by Formula 1-1; three of R₅ₐ to R₅ₑ are each a group represented by Formula 1-1 and two of R_{5f} to R₅ⱼ are each a group represented by Formula 1-1; two of R₅ₐ to R₅ₑ are each a group represented by Formula 1-1 and three of R_{5f} to R₅ⱼ are each a group represented by Formula 1-1; one of R₅ₐ to R₅ₑ is a group represented by Formula 1-1 and four of R_{5f} to R₅ⱼ are each a group represented by Formula 1-1; or
(x) R₁ₐ to R_{1d} are each a group represented by Formula 1-1 and two of R₂ₐ to R_{2d} are each a group represented by Formula 1-1; R₁ₐ to R_{1d} are each a group represented by Formula 1-1, one of R₂ₐ to R_{2d} is a group represented by Formula 1-1, and one of R₃ₐ to R_{3c} is a group represented by Formula 1-1; R₁ₐ to R_{1d} are each a group represented by Formula 1-1 and two of R₃ₐ to R_{3c} are each a group represented by Formula 1-1; R₁ₐ to R_{1d} are each a group represented by Formula 1-1 and two of R₅ₐ to R₅ₑ are each a group represented by Formula 1-1; R₁ₐ to R_{1d} are each a group represented by Formula 1-1 and two of R_{5f} to R₅ⱼ are each a group represented by Formula 1-1; R₁ₐ to R_{1d} are each a group represented by Formula 1-1 one of R₂ₐ to R_{2d} is a group represented by Formula 1-1 and one of R₅ₐ to R₅ₑ is a group represented by Formula 1-1; R₁ₐ to R_{1d} are each a group represented by Formula 1-1, one of R₂ₐ to R_{2d} is a group represented by Formula 1-1 and one of R_{5f} to R₅ⱼ is a group represented by Formula 1-1; R₁ₐ to R_{1d} are each a group represented by Formula 1-1, one of R₃ₐ to R_{3c} is a group represented by Formula 1-1 and one of R₅ₐ to R₅ₑ is a group represented by Formula 1-1; R₁ₐ to R_{1d} are each a group represented by Formula 1-1, one of R₃ₐ to R_{3c} is a group represented by Formula 1-1 and one of R_{5f} to R₅ⱼ is a group represented by Formula 1-1; R₁ₐ to R_{1d} are each a group represented by Formula 1-1, one of R₅ₐ to R₅ₑ is a group represented by Formula 1-1 and one of R_{5f} to R₅ⱼ is a group represented by Formula 1-1; three of R₁ₐ to R_{1d} are each a group represented by Formula 1-1 and three of R₂ₐ to R_{2d} are each a group represented by Formula 1-1; three of R₁ₐ to R_{1d} are each a group represented by Formula 1-1, two of R₂ₐ to R_{2d} are each a group represented by Formula 1-1, and one of R₃ₐ to R_{3c} is a group represented by Formula 1-1; three of R₁ₐ to R_{1d} are each a group represented by Formula 1-1, two of R₂ₐ to R_{2d} are each a group represented by Formula 1-1, and one of R₅ₐ to R₅ₑ is a group represented by Formula 1-1; three of R₁ₐ to R_{1d} are each a group represented by Formula 1-1, two of R₂ₐ to R_{2d} are each a group represented by Formula 1-1, and one of R_{5f} to R₅ⱼ is a group represented by Formula 1-1; three of R₁ₐ to R_{1d} are each a group represented by Formula 1-1, one of R₂ₐ to R_{2d} is a group represented by Formula 1-1, and two of R₃ₐ to R_{3c} are each a group represented by Formula 1-1; three of R₁ₐ to R_{1d} are each a group represented by Formula 1-1, one of R₂ₐ to R_{2d} is a group represented by Formula 1-1, and two of R₅ₐ to R₅ₑ are each a group represented by Formula 1-1; three of R₁ₐ to R_{1d} are each a group represented by Formula 1-1, one of R₂ₐ to R_{2d} is a group represented by Formula 1-1, and two of R_{5f} to R₅ⱼ are each a group represented by Formula 1-1; three of R₁ₐ to R_{1d} are each a group represented by Formula 1-1, one of R₂ₐ to R_{2d} is a group represented by Formula 1-1, one of R₅ₐ to R₅ₑ is a group represented by Formula 1-1 and one of R₁ₐ to R_{1d} is a group represented by Formula 1-1; three of R₁ₐ to R_{1d} are each a group represented by Formula 1-1 and R₃ₐ to R_{3c} are each a group represented by Formula 1-1; three of R₁ₐ to R_{1d} are each a group represented by Formula 1-1 and two of R₃ₐ to R_{3c} are each a group represented by Formula 1-1 and one of R₅ₐ to R₅ₑ is a group represented by Formula 1-1; three of R₁ₐ to R_{1d} are each a group represented by Formula 1-1 and two of R₃ₐ to R_{3c} are each a group represented by Formula 1-1 and one of R_{5f} to R₅ⱼ is a group represented by Formula 1-1; three of R₁ₐ to R_{1d} are each a group represented by Formula 1-1, one of R₃ₐ to R_{3c} is a group represented by Formula 1-1 and two of R₅ₐ to R₅ₑ are each a group represented by Formula 1-1; three of R₁ₐ to R_{1d} are each a group represented by Formula 1-1, one of R₃ₐ to R_{3c} is a group represented by Formula 1-1 and two of R_{5f} to R₅ⱼ are each a group represented by Formula 1-1; three of R₁ₐ to R_{1d} are each a group represented by Formula 1-1, one of R₃ₐ to R_{3c} is a group represented by Formula 1-1, one of R₅ₐ to R₅ₑ is a group represented by Formula 1-1 and one of R_{5f} t to R₅ⱼ is a group represented by Formula 1-1; two of R₁ₐ to R_{1d} are each a group represented by Formula 1-1 and R₂ₐ to R_{2d} are each a group represented by Formula 1-1; two of R₁ₐ to R_{1d} are each a group represented by Formula 1-1, three of R₂ₐ to R_{2d} are each a group represented by Formula 1-1, and one of R₃ₐ to R_{3c} is a group represented by Formula 1-1; two of R₁ₐ to R_{1d} are each a group represented by Formula 1-1, three of R₂ₐ to R_{2d} are each a group represented by Formula 1-1, and one of R₅ₐ to R₅ₑ is a group represented by Formula 1-1; two of R₁ₐ to R_{1d} are each a group represented by Formula 1-1, three of R₂ₐ to R_{2d} are each a group represented by Formula 1-1, and one of R_{5f} to R₅ⱼ is a group represented by Formula 1-1; two of R₁ₐ to R_{1d} are each a group represented by Formula 1-1, two of R₂ₐ to R_{2d} are each a group represented by Formula 1-1, and two of R₃ₐ to R_{3c} are each a group represented by Formula 1-1; two of R₁ₐ to R_{1d} are each a group represented by Formula 1-1, two of R₂ₐ to R_{2d} are each a group represented by Formula 1-1, one of R₃ₐ to R_{3c} is a group represented by Formula 1-1 and one of R₅ₐ to R₅ₑ is a group represented by Formula 1-1; two of R₁ₐ to R_{1d} are each a group represented by Formula 1-1, two of R₂ₐ to R_{2d} are each a group represented by Formula 1-1, one of R₃ₐ to R_{3c} is a group represented by Formula 1-1 and one of R_{5f} to R₅ⱼ is a group represented by Formula 1-1; two of R₁ₐ to R_{1d} are each a group represented by Formula 1-1, two of R₂ₐ to R_{2d} are each a group represented by Formula 1-1, one of R₅ₐ to R₅ₑ is a group represented by Formula 1-1 and one of R_{5f} to R₅ⱼ is a group represented by Formula 1-1; two of R₁ₐ to R_{1d} are each a group represented by Formula 1-1, one of R₂ₐ to R_{2d} is a group represented by Formula 1-1, and R₃ₐ to R_{3c} are each a group represented by Formula 1-1; two of R₁ₐ to R_{1d} are each a group represented by Formula 1-1, one of R₂ₐ to R_{2d} is a group represented by Formula 1-1, and R₃ₐ to R_{3c} are each a group represented by Formula 1-1; two of R₁ₐ to R_{1d} are each a group represented by Formula 1-1, one of R₂ₐ to R_{2d} is a group represented by Formula 1-1, two of R₃ₐ to R_{3c} are each a group represented by Formula 1-1 and one of R₅ₐ to R₅ₑ is a group represented by Formula 1-1; two of R₁ₐ to R_{1d} are each a group represented by Formula 1-1, one of R₂ₐ to R_{2d} is a group represented by Formula 1-1, two of R₃ₐ to R_{3c} are each a group represented by Formula 1-1 and one of R_{5f} to R₅ⱼ is a group represented by Formula 1-1; two of R₁ₐ to R_{1d} are each a group represented by Formula 1-1, one of R₂ₐ to R_{2d} is a group represented by Formula 1-1, one of R₃ₐ to R_{3c} is a group represented by Formula 1-1 and two of R₅ₐ to R₅ₑ are each a group represented by Formula 1-1; two of R₁ₐ to R_{1d} are each a group represented by Formula 1-1, one of R₂ₐ to R_{2d} is a group represented by Formula 1-1, one of R₃ₐ to R_{3c} is a group represented by Formula 1-1 and two of R_{5f} to R₅ⱼ are each a group represented by Formula 1-1; two of R₁ₐ to R_{1d} are each a group represented by Formula 1-1, one of R₂ₐ to R_{2d} is a group represented by Formula 1-1, one of R₃ₐ to R_{3c} is a group represented by Formula 1-1, one of R₅ₐ to R₅ₑ is a group represented by Formula 1-1 and one of R_{5f} to R₅ⱼ is a group represented by Formula 1-1; two of R₁ₐ to R_{1d} are each a group represented by Formula 1-1, one of R₂ₐ to R_{2d} is a group represented by Formula 1-1, and three of R₅ₐ to R₅ₑ are each a group represented by Formula 1-1; two of R₁ₐ to R_{1d} are each a group represented by Formula 1-1, one of R₂ₐ to R_{2d} is a group represented by Formula 1-1, two of R₅ₐ to R₅ₑ are each a group represented by Formula 1-1 and one of R_{5f} to R₅ⱼ is a group represented by Formula 1-1; two of R₁ₐ to R_{1d} are each a group represented by Formula 1-1, one of R₂ₐ to R_{2d} is a group represented by Formula 1-1, one of R₅ₐ to R₅ₑ is a group represented by Formula 1-1 and two of R_{5f} to R₅ⱼ are each a group represented by Formula 1-1; two of R₁ₐ to R_{1d} are each a group represented by Formula 1-1, one of R₂ₐ to R_{2d} is a group represented by Formula 1-1 and three of R_{5f} to Rⱼ are each a group represented by Formula 1-1; one of R₁ₐ to R_{1d} is a group represented by Formula 1-1, R₂ₐ to R_{2d} are each a group represented by Formula 1-1, and one of R₃ₐ to R_{3c} is a group represented by Formula 1-1; one of R₁ₐ to R_{1d} is a group represented by Formula 1-1, R₂ₐ to R_{2d} are each a group represented by Formula 1-1, and one of R_{5f} to R₅ⱼ is a group represented by Formula 1-1; one of R₁ₐ to R_{1d} is a group represented by Formula 1-1, R₂ₐ to R_{2d} are each a group represented by Formula 1-1, and one of R_{5f} to R₅ⱼ is a group represented by Formula 1-1; one of R₁ₐ to R_{1d} is a group represented by Formula 1-1, three of R₂ₐ to R_{2d} are each a group represented by Formula 1-1, and two of R₃ₐ to R_{3c} are each a group represented by Formula 1-1; one of R₁ₐ to R_{1d} is a group represented by Formula 1-1, three of R₂ₐ to R_{2d} are each a group represented by Formula 1-1, one of R₃ₐ to R_{3c} is a group represented by Formula 1-1 and one of R₅ₐ to R₅ₑ is a group represented by Formula 1-1; one of R₁ₐ to R_{1d} is a group represented by Formula 1-1, three of R₂ₐ to R_{2d} are each a group represented by Formula 1-1, one of R₃ₐ to R_{3c} is a group represented by Formula 1-1 and one of R_{5f} to R₅ⱼ is a group represented by Formula 1-1; one of R₁ₐ to R_{1d} is a group represented by Formula 1-1, three of R₂ₐ to R_{2d} are each a group represented by Formula 1-1, two of R₅ₐ to R₅ₑ are each a group represented by Formula 1-1; one of R₁ₐ to R_{1d} is a group represented by Formula 1-1, three of R₂ₐ to R_{2d} are each a group represented by Formula 1-1, one of R₅ₐ to R₅ₑ is a group represented by Formula 1-1 and one of R_{5f} to R₅ⱼ is a group represented by Formula 1-1; one of R₁ₐ to R_{1d} is a group represented by Formula 1-1, three of R₂ₐ to R_{2d} are each a group represented by Formula 1-1 and two of R_{5f} to R₅ⱼ is a group represented by Formula 1-1; one of R₁ₐ to R_{1d} is a group represented by Formula 1-1, two of R₂ₐ to R_{2d} are each a group represented by Formula 1-1, and R₃ₐ to R_{3c} are each a group represented by Formula 1-1; one of R₁ₐ to R_{1d} is a group represented by Formula 1-1, two of R₂ₐ to R_{2d} are each a group represented by Formula 1-1, two of R₃ₐ to R_{3c} are each a group represented by Formula 1-1, one of R₅ₐ to R₅ₑ is a group represented by Formula 1-1; one of R₁ₐ to R_{1d} is a group represented by Formula 1-1, two of R₂ₐ to R_{2d} are each a group represented by Formula 1-1, two of R₃ₐ to R_{3c} are each a group represented by Formula 1-1, one of R_{5f} to R₅ⱼ is a group represented by Formula 1-1; one of R₁ₐ to R_{1d} is a group represented by Formula 1-1, two of R₂ₐ to R_{2d} are each a group represented by Formula 1-1, one of R₃ₐ to R_{3c} is a group represented by Formula 1-1, two of R₅ₐ to R₅ₑ are each a group represented by Formula 1-1; one of R₁ₐ to R_{1d} is a group represented by Formula 1-1, two of R₂ₐ to R_{2d} are each a group represented by Formula 1-1, one of R₃ₐ to R_{3c} is a group represented by Formula 1-1, one of R₅ₐ to R₅ₑ is a group represented by Formula 1-1 and one of R_{5f} to R₅ⱼ is a group represented by Formula 1-1; one of R₁ₐ to R_{1d} is a group represented by Formula 1-1, two of R₂ₐ to R_{2d} are each a group represented by Formula 1-1, one of R₃ₐ to R_{3c} is a group represented by Formula 1-1 and two of R_{5f} to R₅ⱼ is a group represented by Formula 1-1; one of R₁ₐ to R_{1d} is a group represented by Formula 1-1, two of R₂ₐ to R_{2d} are each a group represented by Formula 1-1, and three of R₅ₐ to R₅ₑ are each a group represented by Formula 1-1; one of R₁ₐ to R_{1d} is a group represented by Formula 1-1, two of R₂ₐ to R_{2d} are each a group represented by Formula 1-1, two of R₅ₐ to R₅ₑ are each a group represented by Formula 1-1 and one of R_{5f} to R₅ⱼ is a group represented by Formula 1-1; one of R₁ₐ to R_{1d} is a group represented by Formula 1-1, two of R₂ₐ to R_{2d} are each a group represented by Formula 1-1, one of R₅ₐ to R₅ₑ is a group represented by Formula 1-1 and two of R_{5f} to R₅ⱼ are each a group represented by Formula 1-1; one of R₁ₐ to R_{1d} is a group represented by Formula 1-1, two of R₂ₐ to R_{2d} are each a group represented by Formula 1-1 and three of R_{5f} to R₅ⱼ are each a group represented by Formula 1-1; one of R₁ₐ to R_{1d} is a group represented by Formula 1-1, one of R₂ₐ to R_{2d} is a group represented by Formula 1-1, R₃ₐ to R_{3c} are each a group represented by Formula 1-1 and one of R₅ₐ to R₅ₑ is a group represented by Formula 1-1; one of R₁ₐ to R_{1d} is a group represented by Formula 1-1, one of R₂ₐ to R_{2d} are each a group represented by Formula 1-1, R₃ₐ to R_{3c} are each a group represented by Formula 1-1 and one of R_{5f} to R₅ⱼ is a group represented by Formula 1-1; one of R₁ₐ to R_{1d} is a group represented by Formula 1-1, one of R₂ₐ to R_{2d} is a group represented by Formula 1-1, two of R₃ₐ to R_{3c} are each a group represented by Formula 1-1 and two of R₅ₐ to R₅ₑ are each a group represented by Formula 1-1; one of R₁ₐ to R_{1d} is a group represented by Formula 1-1, one of R₂ₐ to R_{2d} is a group represented by Formula 1-1, two of R₃ₐ to R_{3c}; are each a group represented by Formula 1-1 and two of R_{5f} to Rⱼ are each a group represented by Formula 1-1; one of R₁ₐ to R_{1d} is a group represented by Formula 1-1, one of R₂ₐ to R_{2d} is a group represented by Formula 1-1, two of R₃ₐ to R_{3c} are each a group represented by Formula 1-1, one of R₅ₐ to R₅ₑ is a group represented by Formula 1-1 and one of R_{5f} to Rⱼ is a group represented by Formula 1-1; one of R₁ₐ to R_{1d} is a group represented by Formula 1-1, one of R₂ₐ to R_{2d} is a group represented by Formula 1-1, one of R₃ₐ to R_{3c} is a group represented by Formula 1-1 and three of R₅ₐ to R₅ₑ are each a group represented by Formula 1-1; one of R₁ₐ to R_{1d} is a group represented by Formula 1-1, one of R₂ₐ to R_{2d} is a group represented by Formula 1-1, one of R₃ₐ to R_{3c} is a group represented by Formula 1-1, two of R₅ₐ to R₅ₑ are each a group represented by Formula 1-1 and one of R_{5f} to R₅ⱼ is a group represented by Formula 1-1; one of R₁ₐ to R_{1d} is a group represented by Formula 1-1, one of R₂ₐ to R_{2d} is a group represented by Formula 1-1, one of R₃ₐ to R_{3c} is a group represented by Formula 1-1, one of R₅ₐ to R₅ₑ is a group represented by Formula 1-1 and two of R_{5f} to Rⱼ are each a group represented by Formula 1-1; one of R₁ₐ to R_{1d} is a group represented by Formula 1-1, one of R₂ₐ to R_{2d} is a group represented by Formula 1-1, one of R₅ₐ to R₅ₑ is a group represented by Formula 1-1 and three of R_{5f} to R₅ⱼ are each a group represented by Formula 1-1; one of R₁ₐ to R_{1d} is a group represented by Formula 1-1, one of R₂ₐ to R_{2d} is a group represented by Formula 1-1 and four of R₅ₐ to R₅ₑ are each a group represented by Formula 1-1; one of R₁ₐ to R_{1d} is a group represented by Formula 1-1, one of R₂ₐ to R_{2d} is a group represented by Formula 1-1, three of R₅ₐ to R₅ₑ are each a group represented by Formula 1-1, one of R_{5f} to R₅ⱼ is a group represented by Formula 1-1; one of R₁ₐ to R_{1d} is a group represented by Formula 1-1, one of R₂ₐ to R_{2d} is a group represented by Formula 1-1, two of R₅ₐ to R₅ₑ are each a group represented by Formula 1-1, two of R_{5f} to R₅ⱼ are each a group represented by Formula 1-1; one of R₁ₐ to R_{1d} is a group represented by Formula 1-1, one of R₂ₐ to R_{2d} is a group represented by Formula 1-1, one of R₅ₐ to R₅ₑ is a group represented by Formula 1-1 and three of R_{5f} to R₅ⱼ are each a group represented by Formula 1-1; one of R₁ₐ to R_{1d} is a group represented by Formula 1-1, one of R₂ₐ to R_{2d} is a group represented by Formula 1-1 and four of R_{5f} to R₅ⱼ are each a group represented by Formula 1-1; one of R₁ₐ to R_{1d} is a group represented by Formula 1-1, R₃ₐ to R_{3c} are each a group represented by Formula 1-1, two of R₅ₐ to R₅ₑ are each a group represented by Formula 1-1; one of R₁ₐ to R_{1d} is a group represented by Formula 1-1, R₃ₐ to R_{3c} are each a group represented by Formula 1-1, one of R₅ₐ to R₅ₑ is a group represented by Formula 1-1 and one of R_{5f} t to R₅ⱼ is a group represented by Formula 1-1; one of R₁ₐ to R_{1d} is a group represented by Formula 1-1, R₃ₐ to R_{3c} are each a group represented by Formula 1-1 and two of R_{5f} to R₅ⱼ are each a group represented by Formula 1-1; one of R₁ₐ to R_{1d} is a group represented by Formula 1-1, two of R₃ₐ to R_{3c} are each a group represented by Formula 1-1 and three of R₅ₐ to R₅ₑ are each a group represented by Formula 1-1; one of R₁ₐ to R_{1d} is a group represented by Formula 1-1, two of R₃ₐ to R_{3c} are each a group represented by Formula 1-1, two of R₅ₐ to R₅ₑ are each a group represented by Formula 1-1 and one of R_{5f} to R₅ⱼ is a group represented by Formula 1-1; one of R₁ₐ to R_{1d} is a group represented by Formula 1-1, two of R₃ₐ to R_{3c} are each a group represented by Formula 1-1, one of R₅ₐ to R₅ₑ is a group represented by Formula 1-1 and two of R_{5f} to R₅ⱼ are each a group represented by Formula 1-1; one of R₁ₐ to R_{1d} is a group represented by Formula 1-1, two of R₃ₐ to R_{3c} are each a group represented by Formula 1-1 and three of R_{5f} to R₅ⱼ are each a group represented by Formula 1-1; one of R₁ₐ to R_{1d} is a group represented by Formula 1-1, one of R₃ₐ to R_{3c} is a group represented by Formula 1-1 and four of R₅ₐ to R₅ₑ are each a group represented by Formula 1-1; one of R₁ₐ to R_{1d} is a group represented by Formula 1-1, one of R₃ₐ to R_{3c} is a group represented by Formula 1-1, three of R₅ₐ to R₅ₑ are each a group represented by Formula 1-1 and one of R_{5f} to R₅ⱼ; are each a group represented by Formula 1-1; one of R₁ₐ to R_{1d} is a group represented by Formula 1-1; one of R₃ₐ to R_{3c} is a group represented by Formula 1-1, two of R₅ₐ to R₅ₑ are each a group represented by Formula 1-1 and two of R_{5f} to R₅ⱼ are each a group represented by Formula 1-1; one of R₁ₐ to R_{1d} is a group represented by Formula 1-1, one of R₃ₐ to R_{3c} is a group represented by Formula 1-1, one of R₅ₐ to R₅ₑ is a group represented by Formula 1-1 and three of R_{5f} to R₅ⱼ are each a group represented by Formula 1-1; one of R₁ₐ to R_{1d} is a group represented by Formula 1-1, one of R₃ₐ to R_{3c} is a group represented by Formula 1-1 and four of R_{5f} to R₅ⱼ are each a group represented by Formula 1-1; one of R₁ₐ to R_{1d} is a group represented by Formula 1-1 and R₅ₐ to R₅ₑ are each a group represented by Formula 1-1; one of R₁ₐ to R_{1d} is a group represented by Formula 1-1, four of R₅ₐ to R₅ₑ are each a group represented by Formula 1-1 and one of R_{5f} to R₅ⱼ is a group represented by Formula 1-1; one of R₁ₐ to R_{1d} is a group represented by Formula 1-1, three of R₅ₐ to R₅ₑ are each a group represented by Formula 1-1 and two of R_{5f} to R₅ⱼ are each a group represented by Formula 1-1; one of R₁ₐ to R_{1d} is a group represented by Formula 1-1, two of R₅ₐ to R₅ₑ are each a group represented by Formula 1-1 and three of R_{5f} to Rⱼ are each a group represented by Formula 1-1; one of R₁ₐ to R_{1d} is a group represented by Formula 1-1, one of R₅ₐ to R₅ₑ is a group represented by Formula 1-1 and four of R_{5f} to R₅ⱼ are each a group represented by Formula 1-1; one of R₁ₐ to R_{1d} is a group represented by Formula 1-1 and R_{5f} to R₅ⱼ are each a group represented by Formula 1-1; R₂ₐ to R_{2d} are each a group represented by Formula 1-1 and two of R₃ₐ to R_{3c} are each a group represented by Formula 1-1; R₂ₐ to R_{2d} are each a group represented by Formula 1-1, one of R₃ₐ to R_{3c} are each a group represented by Formula 1-1 and one of R₅ₐ to R₅ₑ is a group represented by Formula 1-1; R₂ₐ to R_{2d} are each a group represented by Formula 1-1, one of R₃ₐ to R_{3c} are each a group represented by Formula 1-1 and one of R_{5f} to R₅ⱼ is a group represented by Formula 1-1; R₂ₐ to R_{2d} are each a group represented by Formula 1-1 and two of R₅ₐ to R₅ₑ are each a group represented by Formula 1-1; R₂ₐ to R_{2d} are each a group represented by Formula 1-1, one of R₅ₐ to R₅ₑ is a group represented by Formula 1-1 and one of R_{5f} to R₅ⱼ is a group represented by Formula 1-1; R₂ₐ to R_{2d} are each a group represented by Formula 1-1 and two of R_{5f} to R₅ⱼ are each a group represented by Formula 1-1; three of R₂ₐ to R_{2d} are each a group represented by Formula 1-1 and R₃ₐ to R_{3c} are each a group represented by Formula 1-1; three of R₂ₐ to R_{2d} are each a group represented by Formula 1-1, two of R₃ₐ to R_{3c} are each a group represented by Formula 1-1 and one of R₅ₐ to R₅ₑ is a group represented by Formula 1-1; three of R₂ₐ to R_{2d} are each a group represented by Formula 1-1, two of R₃ₐ to R_{3c} are each a group represented by Formula 1-1 and one of R_{5f} to R₅ⱼ is a group represented by Formula 1-1; three of R₂ₐ to R_{2d} are each a group represented by Formula 1-1, one of R₃ₐ to R_{3c} is a group represented by Formula 1-1 and two of R₅ₐ to R₅ₑ are each a group represented by Formula 1-1; three of R₂ₐ to R_{2d} are each a group represented by Formula 1-1, one of R₃ₐ to R_{3c} is a group represented by Formula 1-1, one of R₅ₐ to R₅ₑ is a group represented by Formula 1-1 and one of R_{5f} to R₅ⱼ is a group represented by Formula 1-1; three of R₂ₐ to R_{2d} are each a group represented by Formula 1-1, one of R₃ₐ to R_{3c} is a group represented by Formula 1-1 and two of R_{5f} to R₅ⱼ are each a group represented by Formula 1-1; three of R₂ₐ to R_{2d} are each a group represented by Formula 1-1 and three of R₅ₐ to R₅ₑ are each a group represented by Formula 1-1; three of R₂ₐ to R_{2d} are each a group represented by Formula 1-1, two of R₅ₐ to R₅ₑ are each a group represented by Formula 1-1 and one of R_{5f} to Rⱼ is a group represented by Formula 1-1; three of R₂ₐ to R_{2d} are each a group represented by Formula 1-1, one of R₅ₐ to R₅ₑ is a group represented by Formula 1-1 and two of R_{5f} to R₅ⱼ are each a group represented by Formula 1-1; three of R₂ₐ to R_{2d} are each a group represented by Formula 1-1 and three of R_{5f} to R₅ⱼ are each a group represented by Formula 1-1; two of R₂ₐ to R_{2d} are each a group represented by Formula 1-1, R₃ₐ to R_{3c} are each a group represented by Formula 1-1 and one of R₅ₐ to R₅ₑ is a group represented by Formula 1-1; two of R₂ₐ to R_{2d} are each a group represented by Formula 1-1, R₃ₐ to R_{3c} are each a group represented by Formula 1-1 and one of R_{5f} to R₅ⱼ is a group represented by Formula 1-1; two of R₂ₐ to R_{2d} are each a group represented by Formula 1-1, two of R₃ₐ to R_{3c} are each a group represented by Formula 1-1 and two of R₅ₐ to R₅ₑ are each a group represented by Formula 1-1; two of R₂ₐ to R_{2d} are each a group represented by Formula 1-1, two of R₃ₐ to R_{3c} are each a group represented by Formula 1-1, one of R₅ₐ to R₅ₑ is a group represented by Formula 1-1 and one of R_{5f} to R₅ⱼ is a group represented by Formula 1-1; two of R₂ₐ to R_{2d} are each a group represented by Formula 1-1, two of R₃ₐ to R_{3c} are each a group represented by Formula 1-1 and two of R_{5f} to R₅ⱼ are each a group represented by Formula 1-1; two of R₂ₐ to R_{2d} are each a group represented by Formula 1-1, one of R₃ₐ to R_{3c} is a group represented by Formula 1-1 and three of R₅ₐ to R₅ₑ are each a group represented by Formula 1-1; two of R₂ₐ to R_{2d} are each a group represented by Formula 1-1, one of R₃ₐ to R_{3c} is a group represented by Formula 1-1, two of R₃ₐ to R_{3c} are each a group represented by Formula 1-1 and one of R_{5f} to R₅ⱼ is a group represented by Formula 1-1; two of R₂ₐ to R_{2d} are each a group represented by Formula 1-1, one of R₃ₐ to R_{3c} is a group represented by Formula 1-1, one of R₅ₐ to R₅ₑ is a group represented by Formula 1-1 and two of R_{5f} to R₅ⱼ are each a group represented by Formula 1-1; two of R₂ₐ to R_{2d} are each a group represented by Formula 1-1, one of R₃ₐ to R_{3c} is a group represented by Formula 1-1 and three of R_{5f} to R₅ⱼ are each a group represented by Formula 1-1; two of R₂ₐ to R_{2d} are each a group represented by Formula 1-1 and four of R₅ₐ to R₅ₑ are each a group represented by Formula 1-1; two of R₂ₐ to R_{2d} are each a group represented by Formula 1-1, three of R₅ₐ to R₅ₑ are each a group represented by Formula 1-1 and one of R_{5f} to R₅ⱼ is a group represented by Formula 1-1; two of R₂ₐ to R_{2d} are each a group represented by Formula 1-1, two of R₃ₐ to R₅ₐ are each a group represented by Formula 1-1 and two of R_{5f} to R₅ⱼ are each a group represented by Formula 1-1; two of R₂ₐ to R_{2d} are each a group represented by Formula 1-1, one of R₅ₐ to R₅ₑ is a group represented by Formula 1-1 and three of R_{5f} to R₅ⱼ are each a group represented by Formula 1-1; two of R₂ₐ to R_{2d} are each a group represented by Formula 1-1 and four of R_{5f} to R₅ⱼ are each a group represented by Formula 1-1; one of R₂ₐ to R_{2d} is a group represented by Formula 1-1, R₃ₐ to R_{3c} are each a group represented by Formula 1-1 and two of R₅ₐ to R₅ₑ are each a group represented by Formula 1-1; one of R₂ₐ to R_{2d} is a group represented by Formula 1-1, R₃ₐ to R_{3c} are each a group represented by Formula 1-1, one of R₅ₐ to R₅ₑ is a group represented by Formula 1-1 and one of R_{5f} to Rⱼ is a group represented by Formula 1-1; one of R₂ₐ to R_{2d} is a group represented by Formula 1-1, R₃ₐ to R_{3c} are each a group represented by Formula 1-1 and two of R_{5f} to R₅ⱼ are each a group represented by Formula 1-1; one of R₂ₐ to R_{2d} is a group represented by Formula 1-1, two of R₃ₐ to R_{3c} are each a group represented by Formula 1-1 and three of R₅ₐ to R₅ₑ are each a group represented by Formula 1-1; one of R₂ₐ to R_{2d} is a group represented by Formula 1-1, two of R₃ₐ to R_{3c} are each a group represented by Formula 1-1, two of R₅ₐ to R₅ₑ are each a group represented by Formula 1-1 and one of R_{5f} to R₅ⱼ is each a group represented by Formula 1-1; one of R₂ₐ to R_{2d} is a group represented by Formula 1-1, two of R₃ₐ to R_{3c} are each a group represented by Formula 1-1, one of R₅ₐ to R₅ₑ is a group represented by Formula 1-1 and two of R_{5f} to R₅ⱼ are each a group represented by Formula 1-1; one of R₂ₐ to R_{2d} is a group represented by Formula 1-1, two of R₃ₐ to R_{3c} are each a group represented by Formula 1-1 and three of R_{5f} to R₅ⱼ are each a group represented by Formula 1-1; one of R₂ₐ to R_{2d} is a group represented by Formula 1-1, one of R₃ₐ to R_{3c} is a group represented by Formula 1-1 and four of R₅ₐ to R₅ₑ are each a group represented by Formula 1-1; one of R₂ₐ to R_{2d} is a group represented by Formula 1-1, one of R₃ₐ to R_{3c} is a group represented by Formula 1-1, three of R₅ₐ to R₅ₑ are each a group represented by Formula 1-1 and one of R_{5f} to R₅ⱼ is a group represented by Formula 1-1; one of R₂ₐ to R_{2d} is a group represented by Formula 1-1, one of R₃ₐ to R_{3c} is a group represented by Formula 1-1, two of R₅ₐ to R₅ₑ are each a group represented by Formula 1-1 and two of R_{5f} to R₅ⱼ are each a group represented by Formula 1-1; one of R₂ₐ to R_{2d} is a group represented by Formula 1-1, one of R₃ₐ to R_{3c} is a group represented by Formula 1-1, one of R₅ₐ to R₃ₐ is a group represented by Formula 1-1 and three of R_{5f} to R₅ⱼ are each a group represented by Formula 1-1; one of R₂ₐ to R_{2d} is a group represented by Formula 1-1, one of R₃ₐ to R_{3c} is a group represented by Formula 1-1 and four of R_{5f} to R₅ⱼ are each a group represented by Formula 1-1; one of R₂ₐ to R_{2d} is a group represented by Formula 1-1, and R₅ₐ to R₅ₑ are each a group represented by Formula 1-1; one of R₂ₐ to R_{2d} is a group represented by Formula 1-1, and R_{5f} to R₅ⱼ are each a group represented by Formula 1-1; R₃ₐ to R_{3c} are each a group represented by Formula 1-1 and three of R₅ₐ to R₅ₑ are each a group represented by Formula 1-1; R₃ₐ to R_{3c} are each a group represented by Formula 1-1, two of R₅ₐ to R₅ₑ are each a group represented by Formula 1-1 and one of R_{5f} to R₅ⱼ is a group represented by Formula 1-1; R₃ₐ to R_{3c} are each a group represented by Formula 1-1, one of R₅ₐ to R₅ₑ is a group represented by Formula 1-1 and two of R_{5f} to R₅ⱼ are each a group represented by Formula 1-1; R₃ₐ to R_{3c} are each a group represented by Formula 1-1 and three of R_{5f} to R₅ⱼ are each a group represented by Formula 1-1; two of R₃ₐ to R_{3c} are each a group represented by Formula 1-1 and four of R₅ₐ to R₅ₑ are each a group represented by Formula 1-1; two of R₃ₐ to R_{3c} are each a group represented by Formula 1-1, three of R₅ₐ to R_{5c} are each a group represented by Formula 1-1 and one of R_{5f} to R₅ⱼ is a group represented by Formula 1-1; two of R₃ₐ to R_{3c} are each a group represented by Formula 1-1, two of R₅ₐ to R₅ₑ are each a group represented by Formula 1-1 and two of R_{5f} to R₅ⱼ are each a group represented by Formula 1-1; two of R₃ₐ to R_{3c} are each a group represented by Formula 1-1, one of R₅ₐ to R₅ₑ is a group represented by Formula 1-1 and three of R_{5f} to R₅ⱼ are each a group represented by Formula 1-1; two of R₃ₐ to R_{3c} are each a group represented by Formula 1-1 and four of R_{5f} to R₅ⱼ are each a group represented by Formula 1-1; one of R₃ₐ to R_{3c} is a group represented by Formula 1-1 and R₅ₐ to R₅ₑ are each a group represented by Formula 1-1; one of R₃ₐ to R_{3c} is a group represented by Formula 1-1 and R_{5f} to R₅ⱼ are each a group represented by Formula 1-1; R₅ₑ to R₅ₐ are each a group represented by Formula 1-1 and one of R_{5f} to R₅ⱼ is a group represented by Formula 1-1; four of R₅ₐ to R₅ₑ are each a group represented by Formula 1-1 and two of R_{5f} to R₅ⱼ are each a group represented by Formula 1-1; three of R₅ₐ to R₅ₑ are each a group represented by Formula 1-1 and three of R_{5f} to R₅ⱼ are each a group represented by Formula 1-1; two of R₅ₐ to R₅ₑ are each a group represented by Formula 1-1 and four of R_{5f} to R₅ⱼ are each a group represented by Formula 1-1; or one of R₅ₐ to R₅ₑ is a group represented by Formula 1-1 and R_{5f} to R₅ⱼ are each a group represented by Formula 1-1.

In one or more embodiments, the polycyclic compound represented by Formula 1 may be represented by one of Compounds 1 to 107:

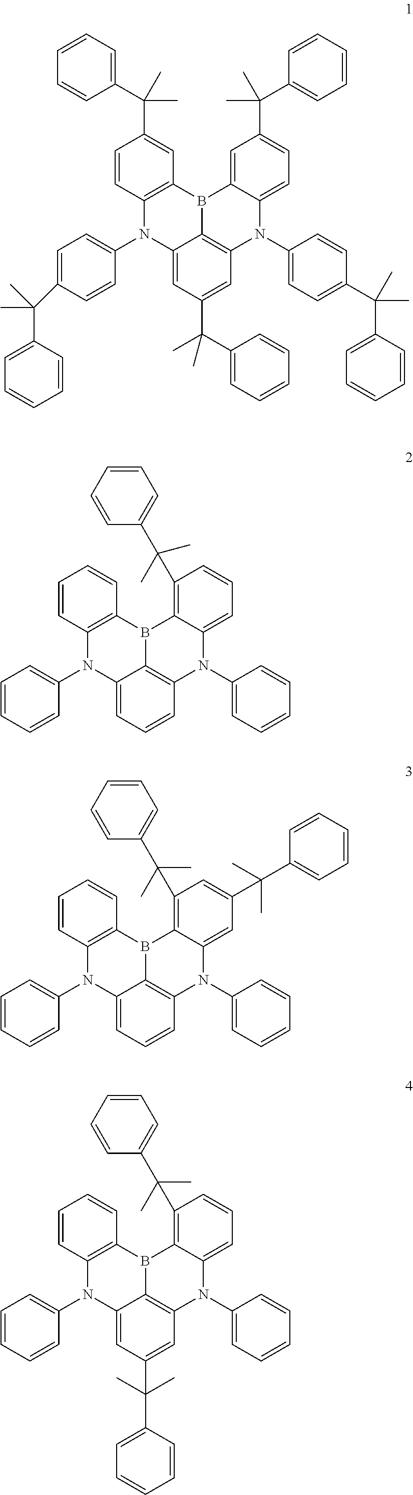 [SMILES: CC(C)(c1ccccc1)c1ccc(N2c3ccc(C(C)(C)c4ccccc4)cc3B3c4cc(C(C)(C)c5ccccc5)ccc4N(c4ccc(C(C)(C)c5ccccc5)cc4)c4cc(C(C)(C)c5ccccc5)cc2c43)cc1 ; CC(C)(c1ccccc1)c1cccc2c1B1c3ccccc3N(c3ccccc3)c3cccc(c31)N2c1ccccc1 ; CC(C)(c1ccccc1)c1cc2c(c(C(C)(C)c3ccccc3)c1)B1c3ccccc3N(c3ccccc3)c3cccc(c31)N2c1ccccc1 ; CC(C)(c1ccccc1)c1cc2c3c(c1)N(c1ccccc1)c1cccc(C(C)(C)c4ccccc4)c1B3c1ccccc1N2c1ccccc1]

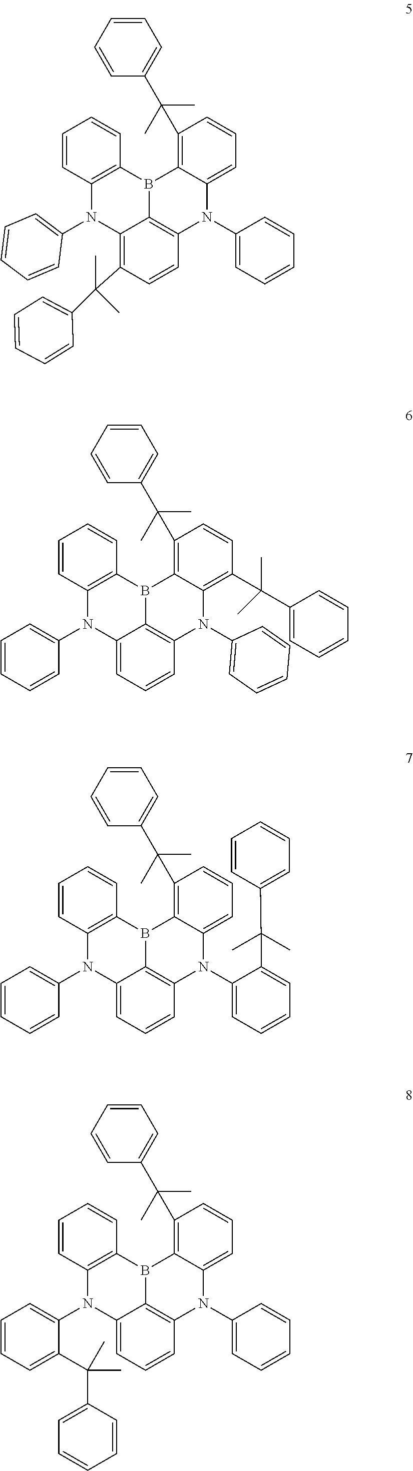 [SMILES: CC(C)(c1ccccc1)c1cccc2c1B1c3ccccc3N(c3ccccc3)c3c(C(C)(C)c4ccccc4)ccc(c31)N2c1ccccc1 ; CC(C)(c1ccccc1)c1ccc(C(C)(C)c2ccccc2)c2c1B1c3ccccc3N(c3ccccc3)c3cccc(c31)N2c1ccccc1 ; CC(C)(c1ccccc1)c1ccccc1N1c2cccc3c2B(c2ccccc2N3c2ccccc2)c2c1cccc2C(C)(C)c1ccccc1 ; CC(C)(c1ccccc1)c1ccccc1N1c2ccccc2B2c3c(cccc31)N(c1ccccc1)c1cccc(C(C)(C)c3ccccc3)c12]

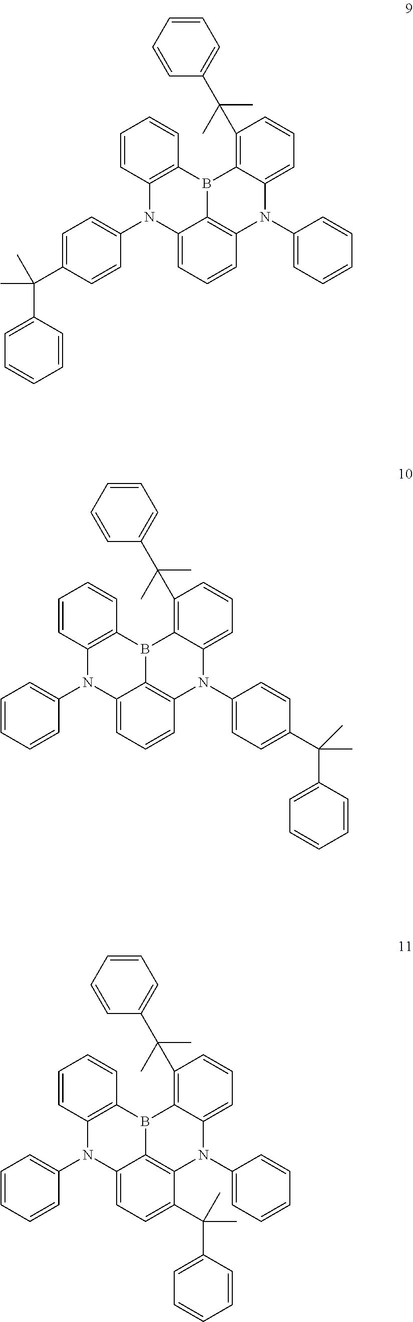 [SMILES: CC(C)(c1ccccc1)c1ccc(N2c3ccccc3B3c4c2cccc4N(c2ccccc2)c2cccc(C(C)(C)c4ccccc4)c23)cc1 ; CC(C)(c1ccccc1)c1ccc(N2c3cccc4c3B(c3ccccc3N4c3ccccc3)c3c2cccc3C(C)(C)c2ccccc2)cc1 ; CC(C)(c1ccccc1)c1cccc2c1B1c3ccccc3N(c3ccccc3)c3ccc(C(C)(C)c4ccccc4)c(c31)N2c1ccccc1]

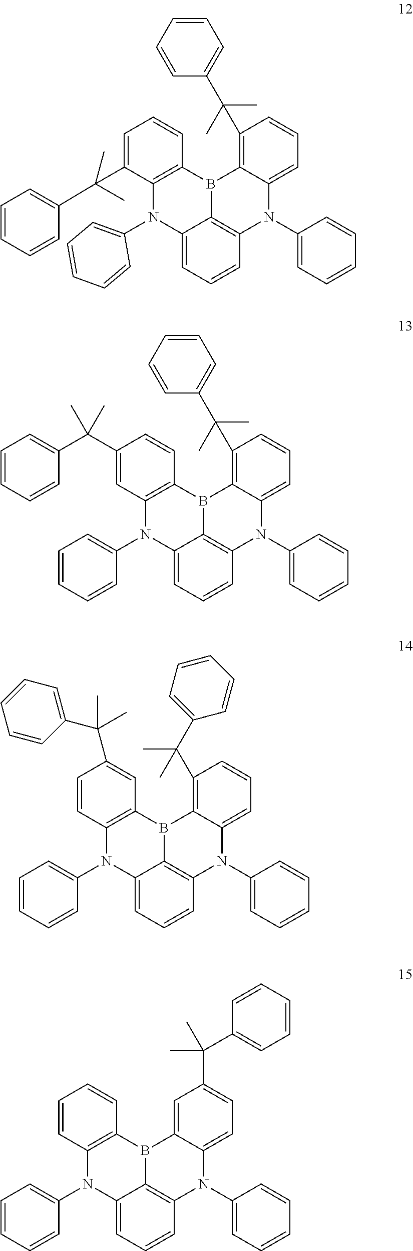 [SMILES: CC(C)(c1ccccc1)c1cccc2c1B1c3cccc(C(C)(C)c4ccccc4)c3N(c3ccccc3)c3cccc(c31)N2c1ccccc1 ; CC(C)(c1ccccc1)c1ccc2c(c1)N(c1ccccc1)c1cccc3c1B2c1c(cccc1C(C)(C)c1ccccc1)N3c1ccccc1 ; CC(C)(c1ccccc1)c1ccc2c(c1)B1c3c(cccc3N(c3ccccc3)c3cccc(C(C)(C)c4ccccc4)c31)N2c1ccccc1 ; CC(C)(c1ccccc1)c1ccc2c(c1)B1c3ccccc3N(c3ccccc3)c3cccc(c31)N2c1ccccc1]

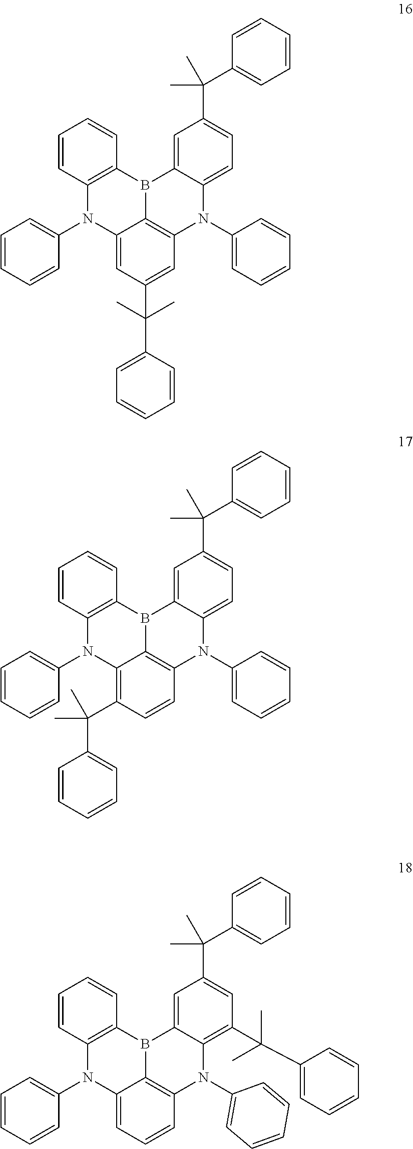 [SMILES: CC(C)(c1ccccc1)c1ccc2c(c1)B1c3ccccc3N(c3ccccc3)c3cc(C(C)(C)c4ccccc4)cc(c31)N2c1ccccc1 ; CC(C)(c1ccccc1)c1ccc2c(c1)B1c3ccccc3N(c3ccccc3)c3c(C(C)(C)c4ccccc4)ccc(c31)N2c1ccccc1 ; CC(C)(c1ccccc1)c1cc2c(c(C(C)(C)c3ccccc3)c1)N(c1ccccc1)c1cccc3c1B2c1ccccc1N3c1ccccc1]

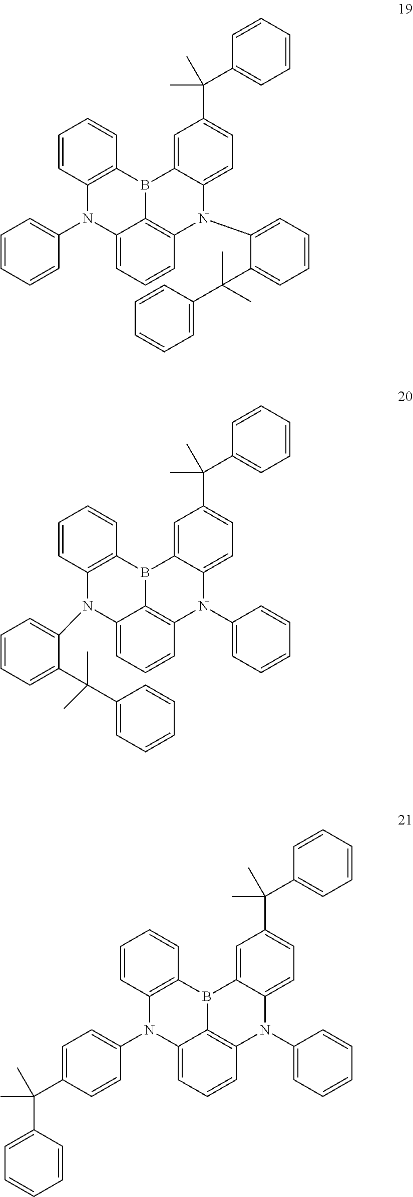 [SMILES: CC(C)(c1ccccc1)c1ccc2c(c1)B1c3ccccc3N(c3ccccc3)c3cccc(c31)N2c1ccccc1C(C)(C)c1ccccc1 ; CC(C)(c1ccccc1)c1ccc2c(c1)B1c3ccccc3N(c3ccccc3C(C)(C)c3ccccc3)c3cccc(c31)N2c1ccccc1 ; CC(C)(c1ccccc1)c1ccc(N2c3ccccc3B3c4cc(C(C)(C)c5ccccc5)ccc4N(c4ccccc4)c4cccc2c43)cc1]

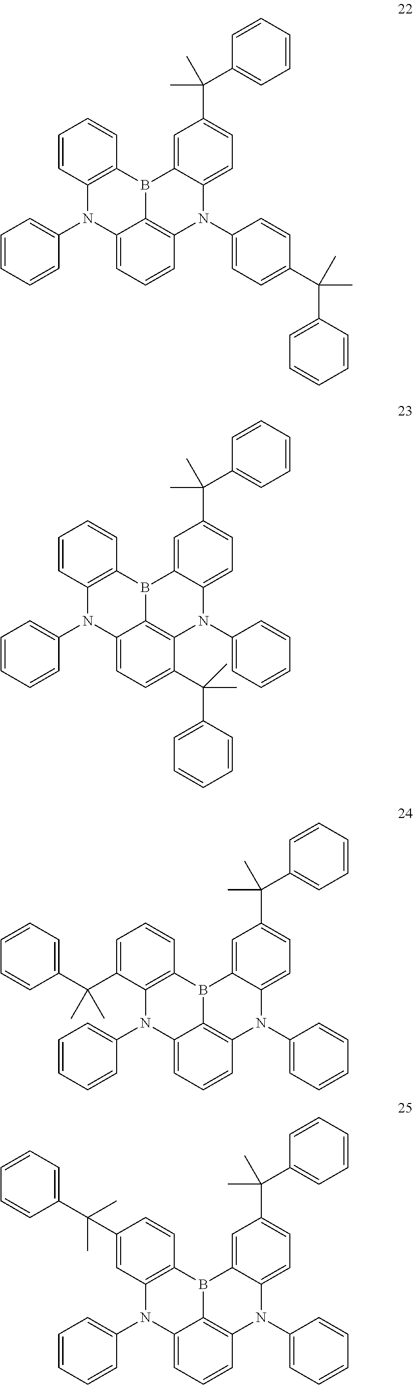

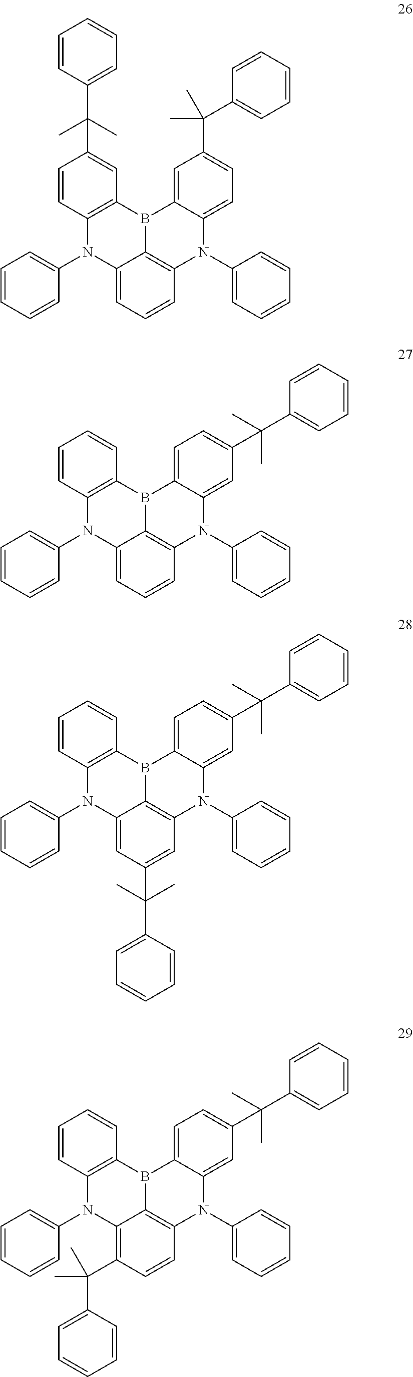 [SMILES: CC(C)(c1ccccc1)c1ccc2c(c1)B1c3cc(C(C)(C)c4ccccc4)ccc3N(c3ccccc3)c3cccc(c31)N2c1ccccc1 ; CC(C)(c1ccccc1)c1ccc2c(c1)N(c1ccccc1)c1cccc3c1B2c1ccccc1N3c1ccccc1 ; CC(C)(c1ccccc1)c1ccc2c(c1)N(c1ccccc1)c1cc(C(C)(C)c3ccccc3)cc3c1B2c1ccccc1N3c1ccccc1 ; CC(C)(c1ccccc1)c1ccc2c(c1)N(c1ccccc1)c1ccc(C(C)(C)c3ccccc3)c3c1B2c1ccccc1N3c1ccccc1]

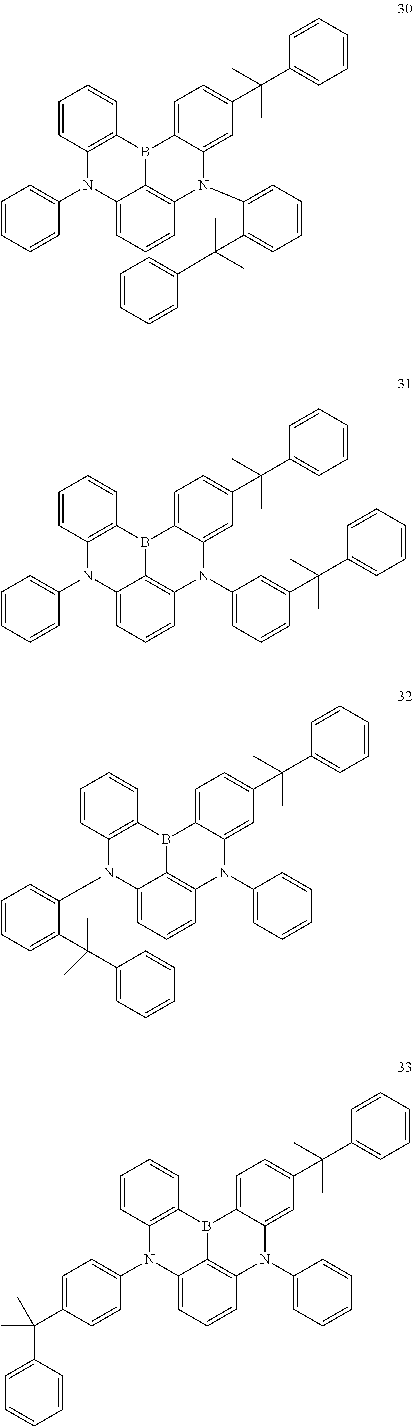 [SMILES: CC(C)(c1ccccc1)c1ccc2c(c1)N(c1ccccc1C(C)(C)c1ccccc1)c1cccc3c1B2c1ccccc1N3c1ccccc1 ; CC(C)(c1ccccc1)c1cccc(N2c3cc(C(C)(C)c4ccccc4)ccc3B3c4ccccc4N(c4ccccc4)c4cccc2c43)c1 ; CC(C)(c1ccccc1)c1ccc2c(c1)N(c1ccccc1)c1cccc3c1B2c1ccccc1N3c1ccccc1C(C)(C)c1ccccc1 ; CC(C)(c1ccccc1)c1ccc(N2c3ccccc3B3c4ccc(C(C)(C)c5ccccc5)cc4N(c4ccccc4)c4cccc2c43)cc1]

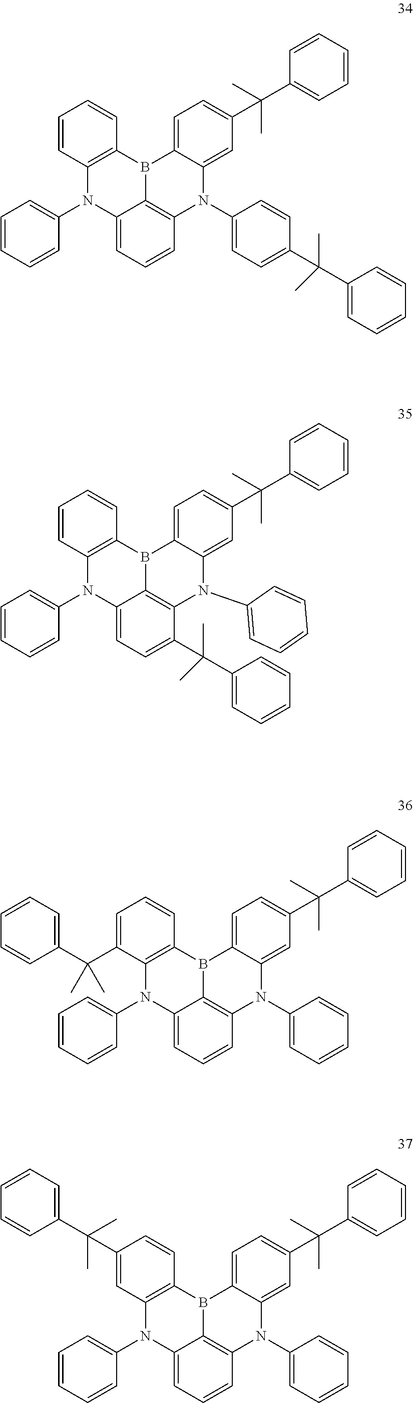 [SMILES: CC(C)(c1ccccc1)c1ccc(N2c3cc(C(C)(C)c4ccccc4)ccc3B3c4ccccc4N(c4ccccc4)c4cccc2c43)cc1 ; CC(C)(c1ccccc1)c1ccc2c(c1)N(c1ccccc1)c1c(C(C)(C)c3ccccc3)ccc3c1B2c1ccccc1N3c1ccccc1 ; CC(C)(c1ccccc1)c1ccc2c(c1)N(c1ccccc1)c1cccc3c1B2c1cccc(C(C)(C)c2ccccc2)c1N3c1ccccc1 ; CC(C)(c1ccccc1)c1ccc2c(c1)N(c1ccccc1)c1cccc3c1B2c1ccc(C(C)(C)c2ccccc2)cc1N3c1ccccc1]

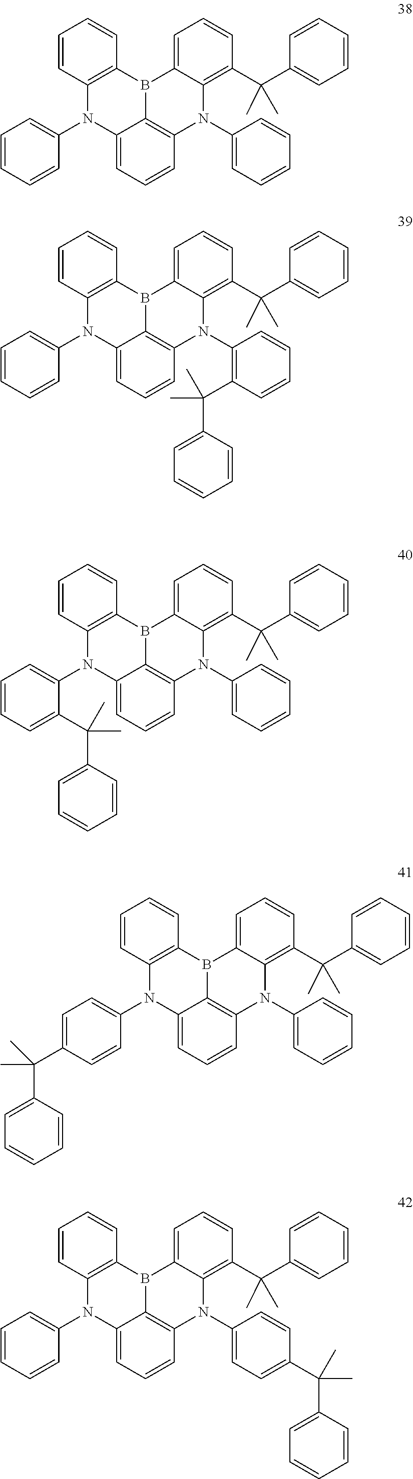 [SMILES: CC(C)(c1ccccc1)c1cccc2c1N(c1ccccc1)c1cccc3c1B2c1ccccc1N3c1ccccc1 ; CC(C)(c1ccccc1)c1ccccc1N1c2cccc3c2B(c2ccccc2N3c2ccccc2)c2cccc(C(C)(C)c3ccccc3)c21 ; CC(C)(c1ccccc1)c1ccccc1N1c2ccccc2B2c3cccc(C(C)(C)c4ccccc4)c3N(c3ccccc3)c3cccc1c32 ; CC(C)(c1ccccc1)c1ccc(N2c3ccccc3B3c4cccc(C(C)(C)c5ccccc5)c4N(c4ccccc4)c4cccc2c43)cc1 ; CC(C)(c1ccccc1)c1ccc(N2c3cccc4c3B(c3ccccc3N4c3ccccc3)c3cccc(C(C)(C)c4ccccc4)c32)cc1]

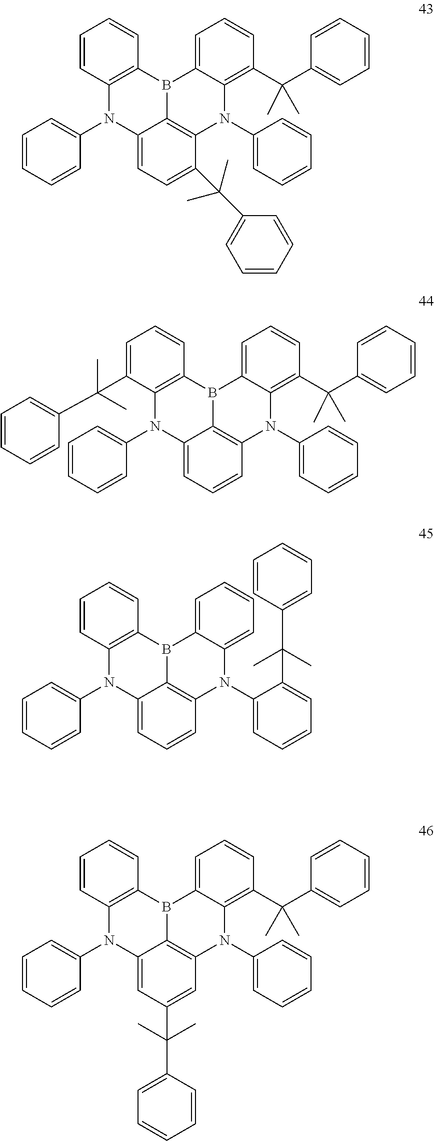 [SMILES: CC(C)(c1ccccc1)c1cccc2c1N(c1ccccc1)c1c(C(C)(C)c3ccccc3)ccc3c1B2c1ccccc1N3c1ccccc1 ; CC(C)(c1ccccc1)c1cccc2c1N(c1ccccc1)c1cccc3c1B2c1cccc(C(C)(C)c2ccccc2)c1N3c1ccccc1 ; CC(C)(c1ccccc1)c1ccccc1N1c2ccccc2B2c3ccccc3N(c3ccccc3)c3cccc1c32 ; CC(C)(c1ccccc1)c1cc2c3c(c1)N(c1ccccc1)c1c(cccc1C(C)(C)c1ccccc1)B3c1ccccc1N2c1ccccc1]

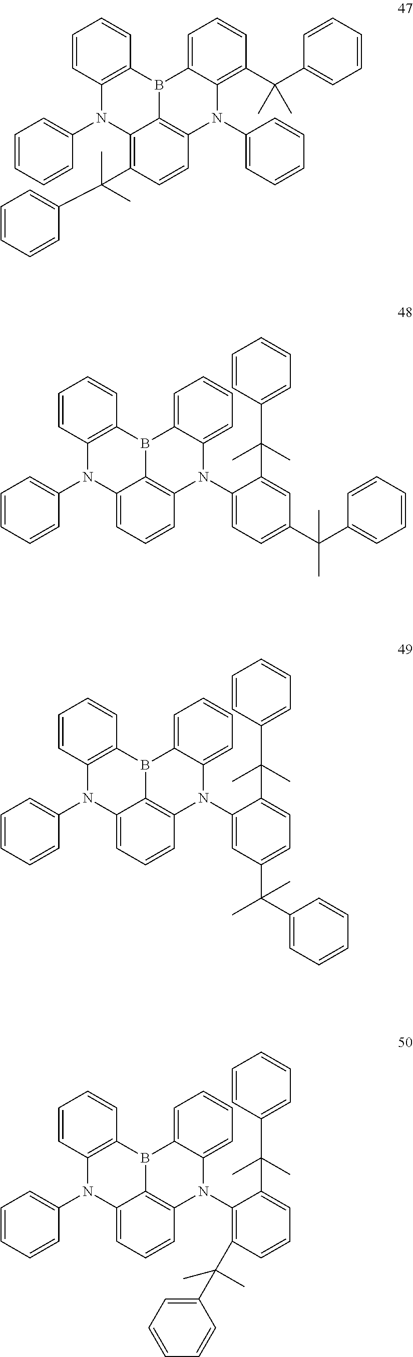 [SMILES: CC(C)(c1ccccc1)c1cccc2c1N(c1ccccc1)c1ccc(C(C)(C)c3ccccc3)c3c1B2c1ccccc1N3c1ccccc1 ; CC(C)(c1ccccc1)c1ccc(N2c3ccccc3B3c4ccccc4N(c4ccccc4)c4cccc2c43)c(C(C)(C)c2ccccc2)c1 ; CC(C)(c1ccccc1)c1ccc(C(C)(C)c2ccccc2)c(N2c3ccccc3B3c4ccccc4N(c4ccccc4)c4cccc2c43)c1 ; CC(C)(c1ccccc1)c1cccc(C(C)(C)c2ccccc2)c1N1c2ccccc2B2c3ccccc3N(c3ccccc3)c3cccc1c32]

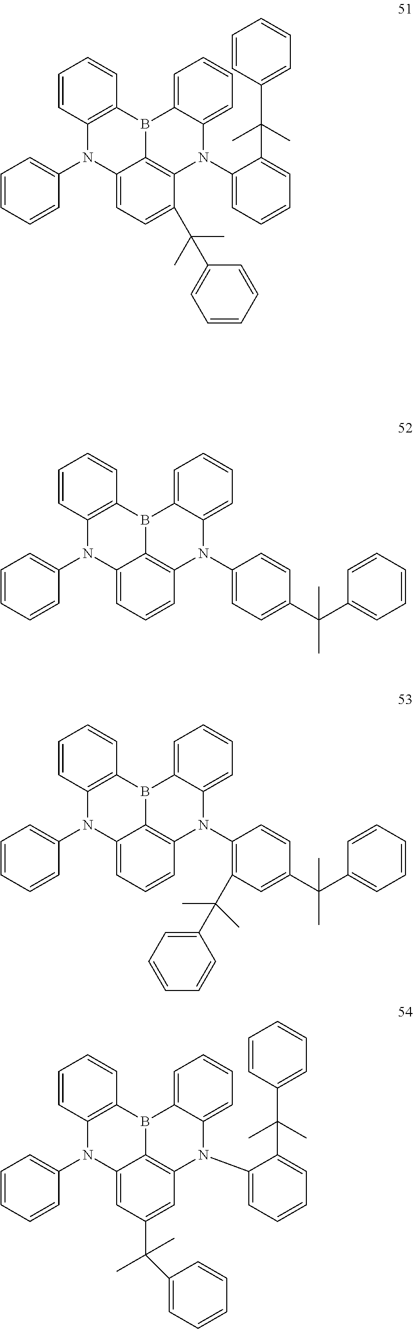 [SMILES: CC(C)(c1ccccc1)c1ccccc1N1c2ccccc2B2c3ccccc3N(c3ccccc3)c3ccc(C(C)(C)c4ccccc4)c1c32 ; CC(C)(c1ccccc1)c1ccc(N2c3ccccc3B3c4ccccc4N(c4ccccc4)c4cccc2c43)cc1 ; CC(C)(c1ccccc1)c1ccc(N2c3ccccc3B3c4ccccc4N(c4ccccc4)c4cccc2c43)c(C(C)(C)c2ccccc2)c1 ; CC(C)(c1ccccc1)c1cc2c3c(c1)N(c1ccccc1C(C)(C)c1ccccc1)c1ccccc1B3c1ccccc1N2c1ccccc1]

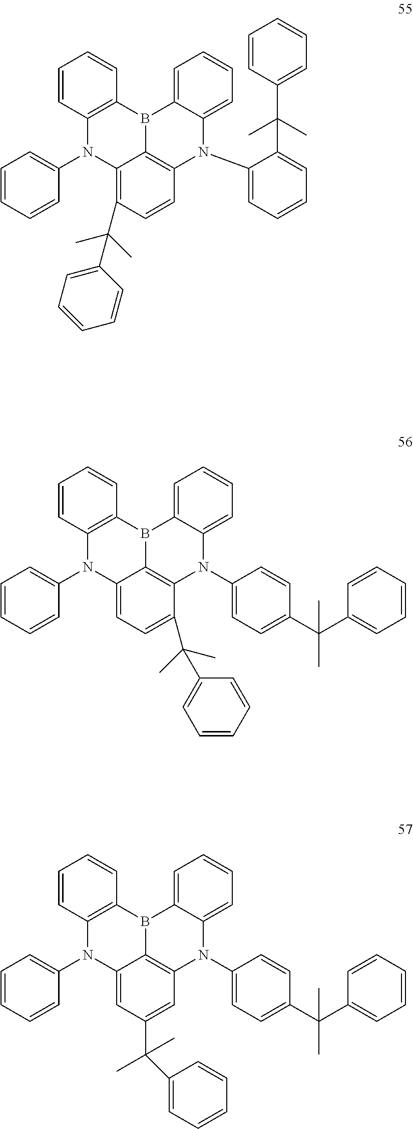 [SMILES: CC(C)(c1ccccc1)c1ccccc1N1c2ccccc2B2c3ccccc3N(c3ccccc3)c3c(C(C)(C)c4ccccc4)ccc1c32 ; CC(C)(c1ccccc1)c1ccc(N2c3ccccc3B3c4ccccc4N(c4ccccc4)c4ccc(C(C)(C)c5ccccc5)c2c43)cc1 ; CC(C)(c1ccccc1)c1ccc(N2c3ccccc3B3c4ccccc4N(c4ccccc4)c4cc(C(C)(C)c5ccccc5)cc2c43)cc1]

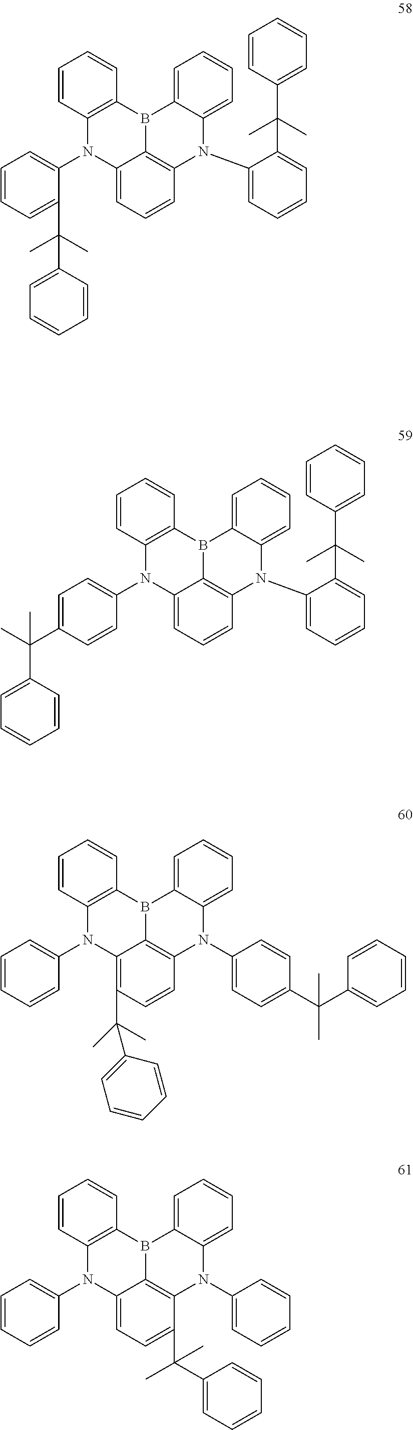 [SMILES: CC(C)(c1ccccc1)c1ccccc1N1c2ccccc2B2c3ccccc3N(c3ccccc3C(C)(C)c3ccccc3)c3cccc1c32 ; CC(C)(c1ccccc1)c1ccc(N2c3ccccc3B3c4ccccc4N(c4ccccc4C(C)(C)c4ccccc4)c4cccc2c43)cc1 ; CC(C)(c1ccccc1)c1ccc(N2c3ccccc3B3c4ccccc4N(c4ccccc4)c4c(C(C)(C)c5ccccc5)ccc2c43)cc1 ; CC(C)(c1ccccc1)c1ccc2c3c1N(c1ccccc1)c1ccccc1B3c1ccccc1N2c1ccccc1]

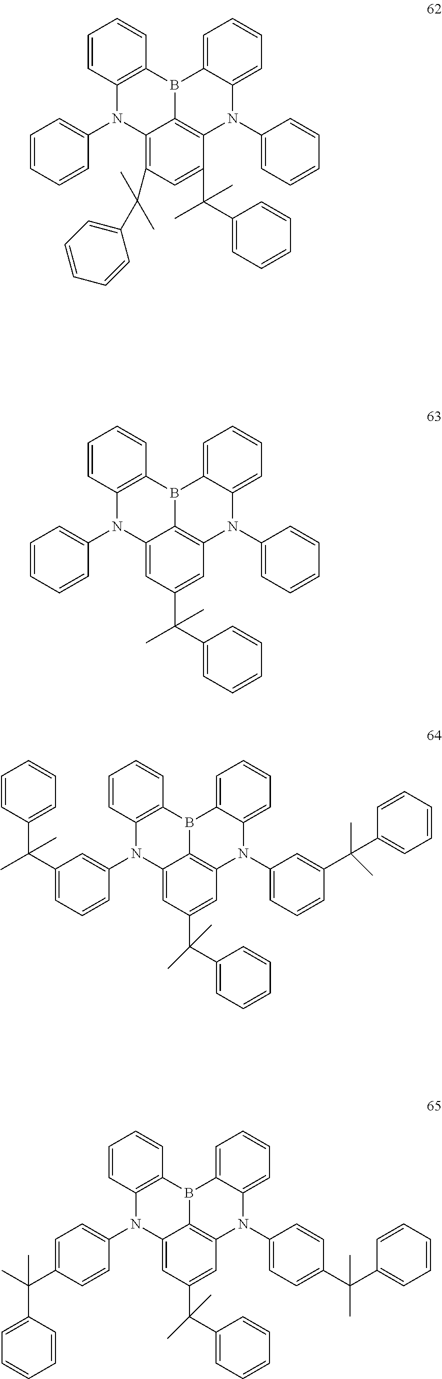 [SMILES: CC(C)(c1ccccc1)c1cc(C(C)(C)c2ccccc2)c2c3c1N(c1ccccc1)c1ccccc1B3c1ccccc1N2c1ccccc1 ; CC(C)(c1ccccc1)c1cc2c3c(c1)N(c1ccccc1)c1ccccc1B3c1ccccc1N2c1ccccc1 ; CC(C)(c1ccccc1)c1cccc(N2c3ccccc3B3c4ccccc4N(c4cccc(C(C)(C)c5ccccc5)c4)c4cc(C(C)(C)c5ccccc5)cc2c43)c1 ; CC(C)(c1ccccc1)c1ccc(N2c3ccccc3B3c4ccccc4N(c4ccc(C(C)(C)c5ccccc5)cc4)c4cc(C(C)(C)c5ccccc5)cc2c43)cc1]

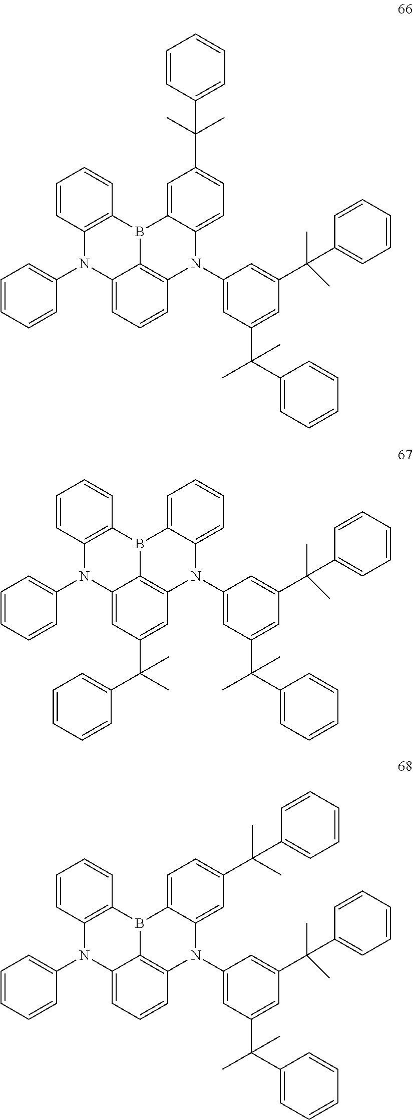 [SMILES: CC(C)(c1ccccc1)c1cc(N2c3ccc(C(C)(C)c4ccccc4)cc3B3c4ccccc4N(c4ccccc4)c4cccc2c43)cc(C(C)(C)c2ccccc2)c1 ; CC(C)(c1ccccc1)c1cc(N2c3ccccc3B3c4ccccc4N(c4ccccc4)c4cc(C(C)(C)c5ccccc5)cc2c43)cc(C(C)(C)c2ccccc2)c1 ; CC(C)(c1ccccc1)c1cc(N2c3cc(C(C)(C)c4ccccc4)ccc3B3c4ccccc4N(c4ccccc4)c4cccc2c43)cc(C(C)(C)c2ccccc2)c1]

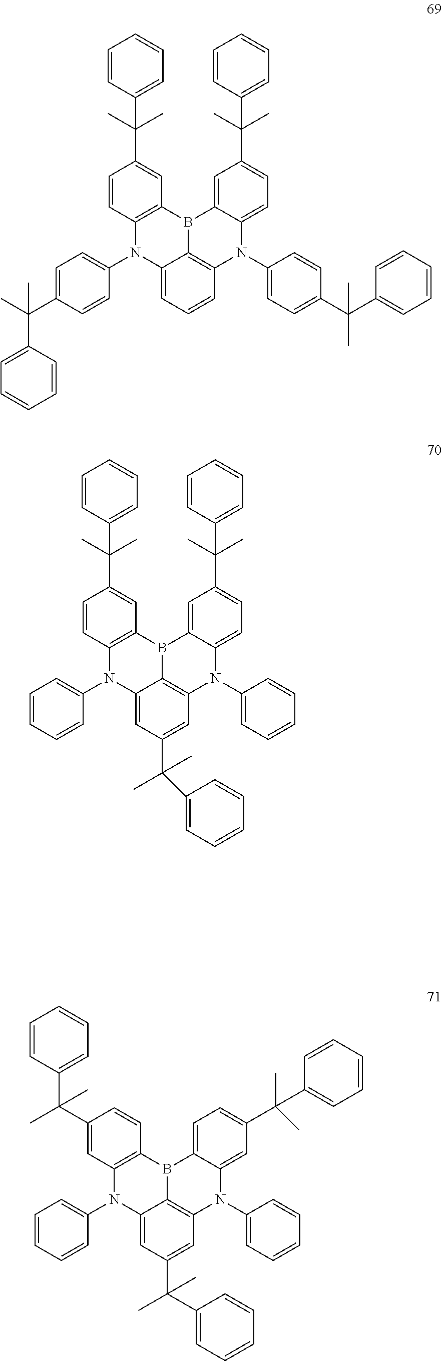 [SMILES: CC(C)(c1ccccc1)c1ccc(N2c3ccc(C(C)(C)c4ccccc4)cc3B3c4cc(C(C)(C)c5ccccc5)ccc4N(c4ccc(C(C)(C)c5ccccc5)cc4)c4cccc2c43)cc1 ; CC(C)(c1ccccc1)c1ccc2c(c1)B1c3cc(C(C)(C)c4ccccc4)ccc3N(c3ccccc3)c3cc(C(C)(C)c4ccccc4)cc(c31)N2c1ccccc1 ; CC(C)(c1ccccc1)c1ccc2c(c1)N(c1ccccc1)c1cc(C(C)(C)c3ccccc3)cc3c1B2c1ccc(C(C)(C)c2ccccc2)cc1N3c1ccccc1]

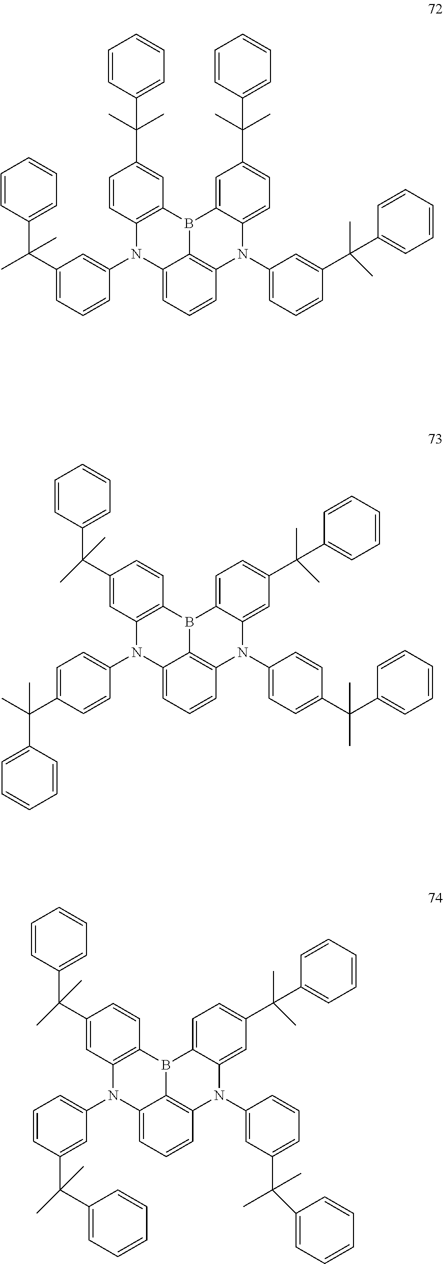 [SMILES: CC(C)(c1ccccc1)c1cccc(N2c3ccc(C(C)(C)c4ccccc4)cc3B3c4cc(C(C)(C)c5ccccc5)ccc4N(c4cccc(C(C)(C)c5ccccc5)c4)c4cccc2c43)c1 ; CC(C)(c1ccccc1)c1ccc(N2c3cc(C(C)(C)c4ccccc4)ccc3B3c4ccc(C(C)(C)c5ccccc5)cc4N(c4ccc(C(C)(C)c5ccccc5)cc4)c4cccc2c43)cc1 ; CC(C)(c1ccccc1)c1cccc(N2c3cc(C(C)(C)c4ccccc4)ccc3B3c4ccc(C(C)(C)c5ccccc5)cc4N(c4cccc(C(C)(C)c5ccccc5)c4)c4cccc2c43)c1]

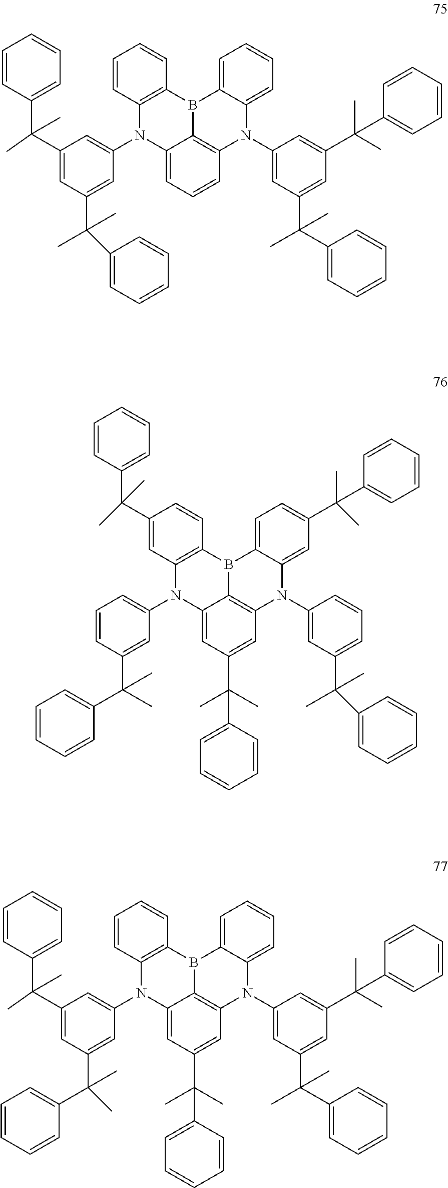 [SMILES: CC(C)(c1ccccc1)c1cc(N2c3ccccc3B3c4ccccc4N(c4cc(C(C)(C)c5ccccc5)cc(C(C)(C)c5ccccc5)c4)c4cccc2c43)cc(C(C)(C)c2ccccc2)c1 ; CC(C)(c1ccccc1)c1cccc(N2c3cc(C(C)(C)c4ccccc4)ccc3B3c4ccc(C(C)(C)c5ccccc5)cc4N(c4cccc(C(C)(C)c5ccccc5)c4)c4cc(C(C)(C)c5ccccc5)cc2c43)c1 ; CC(C)(c1ccccc1)c1cc(N2c3ccccc3B3c4ccccc4N(c4cc(C(C)(C)c5ccccc5)cc(C(C)(C)c5ccccc5)c4)c4cc(C(C)(C)c5ccccc5)cc2c43)cc(C(C)(C)c2ccccc2)c1]

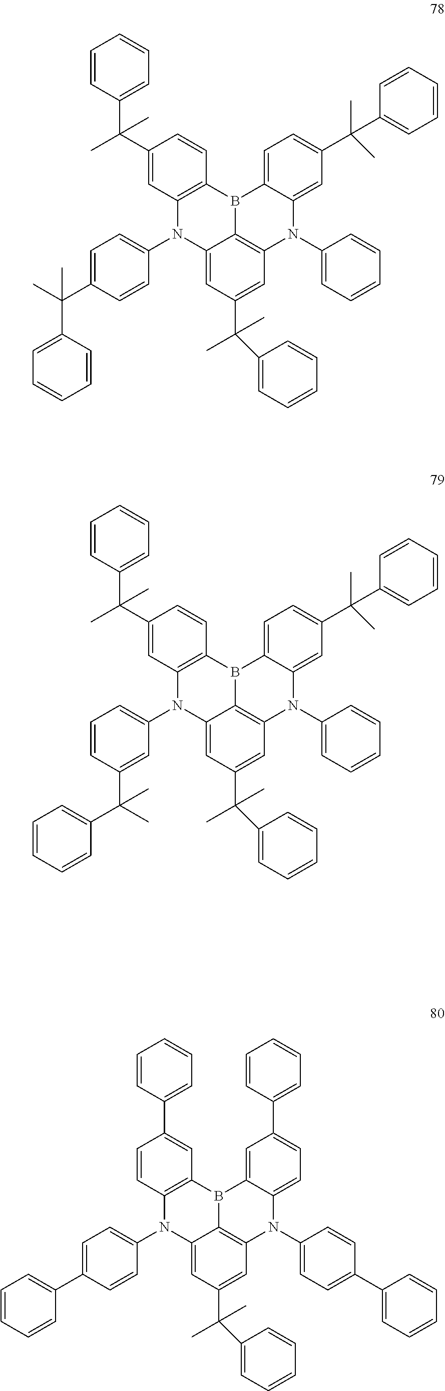 [SMILES: CC(C)(c1ccccc1)c1ccc(N2c3cc(C(C)(C)c4ccccc4)ccc3B3c4ccc(C(C)(C)c5ccccc5)cc4N(c4ccccc4)c4cc(C(C)(C)c5ccccc5)cc2c43)cc1 ; CC(C)(c1ccccc1)c1cccc(N2c3cc(C(C)(C)c4ccccc4)ccc3B3c4ccc(C(C)(C)c5ccccc5)cc4N(c4ccccc4)c4cc(C(C)(C)c5ccccc5)cc2c43)c1 ; CC(C)(c1ccccc1)c1cc2c3c(c1)N(c1ccc(-c4ccccc4)cc1)c1ccc(-c4ccccc4)cc1B3c1cc(-c3ccccc3)ccc1N2c1ccc(-c2ccccc2)cc1]

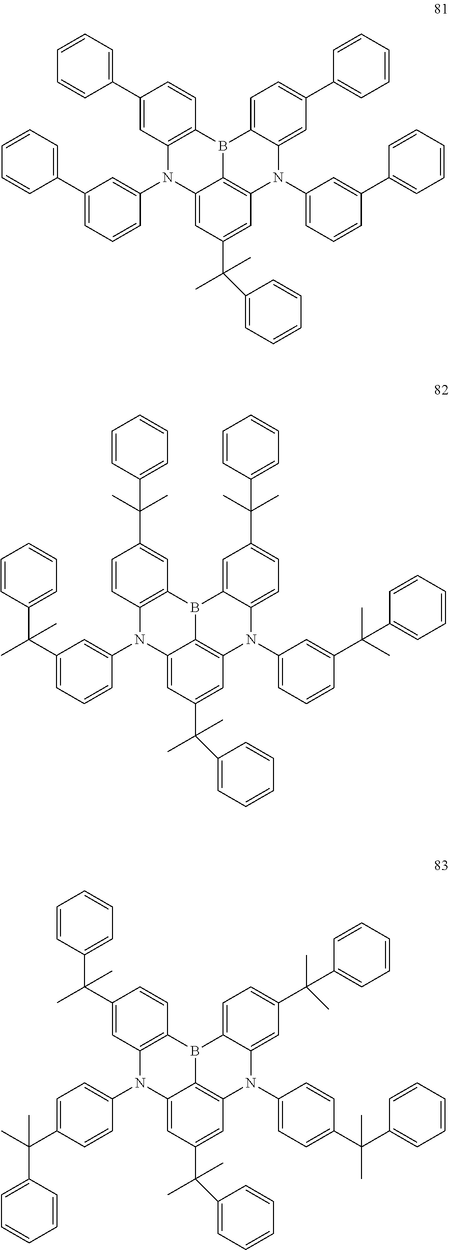 [SMILES: CC(C)(c1ccccc1)c1cc2c3c(c1)N(c1cccc(-c4ccccc4)c1)c1cc(-c4ccccc4)ccc1B3c1ccc(-c3ccccc3)cc1N2c1cccc(-c2ccccc2)c1 ; CC(C)(c1ccccc1)c1cccc(N2c3ccc(C(C)(C)c4ccccc4)cc3B3c4cc(C(C)(C)c5ccccc5)ccc4N(c4cccc(C(C)(C)c5ccccc5)c4)c4cc(C(C)(C)c5ccccc5)cc2c43)c1 ; CC(C)(c1ccccc1)c1ccc(N2c3cc(C(C)(C)c4ccccc4)ccc3B3c4ccc(C(C)(C)c5ccccc5)cc4N(c4ccc(C(C)(C)c5ccccc5)cc4)c4cc(C(C)(C)c5ccccc5)cc2c43)cc1]

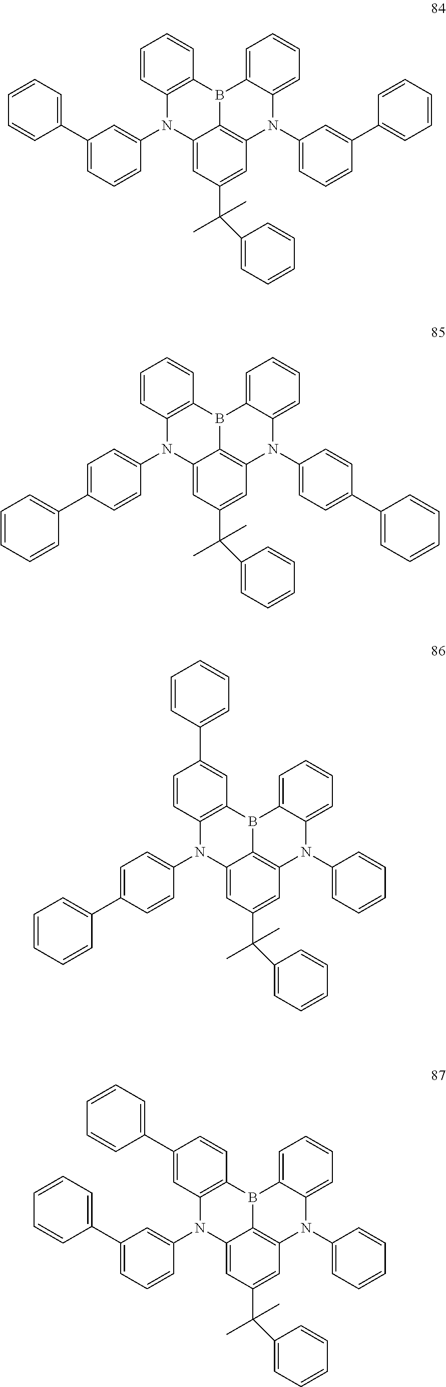 [SMILES: CC(C)(c1ccccc1)c1cc2c3c(c1)N(c1cccc(-c4ccccc4)c1)c1ccccc1B3c1ccccc1N2c1cccc(-c2ccccc2)c1 ; CC(C)(c1ccccc1)c1cc2c3c(c1)N(c1ccc(-c4ccccc4)cc1)c1ccccc1B3c1ccccc1N2c1ccc(-c2ccccc2)cc1 ; CC(C)(c1ccccc1)c1cc2c3c(c1)N(c1ccc(-c4ccccc4)cc1)c1ccc(-c4ccccc4)cc1B3c1ccccc1N2c1ccccc1 ; CC(C)(c1ccccc1)c1cc2c3c(c1)N(c1cccc(-c4ccccc4)c1)c1cc(-c4ccccc4)ccc1B3c1ccccc1N2c1ccccc1]

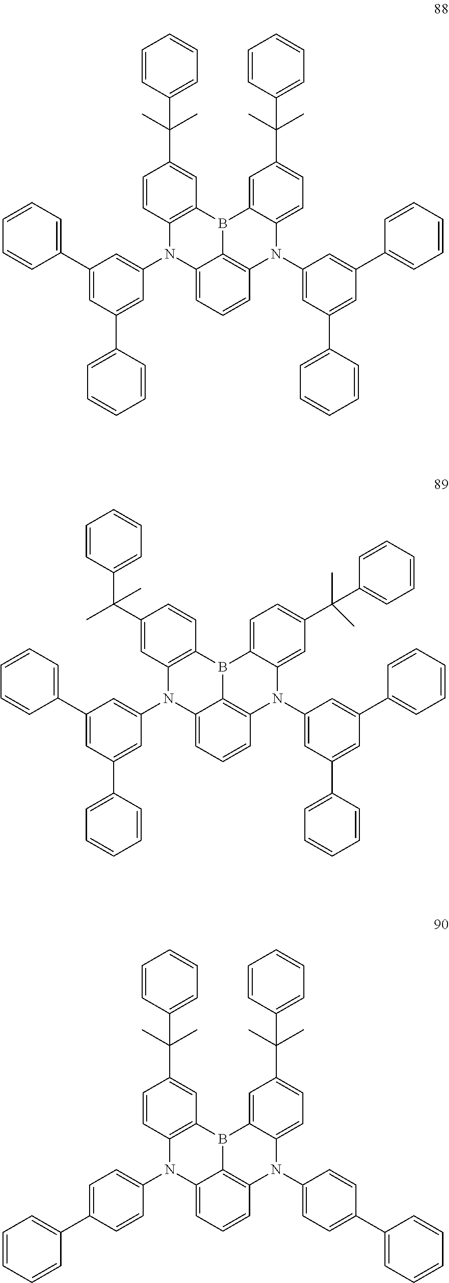 [SMILES: CC(C)(c1ccccc1)c1ccc2c(c1)B1c3cc(C(C)(C)c4ccccc4)ccc3N(c3cc(-c4ccccc4)cc(-c4ccccc4)c3)c3cccc(c31)N2c1cc(-c2ccccc2)cc(-c2ccccc2)c1 ; CC(C)(c1ccccc1)c1ccc2c(c1)N(c1cc(-c3ccccc3)cc(-c3ccccc3)c1)c1cccc3c1B2c1ccc(C(C)(C)c2ccccc2)cc1N3c1cc(-c2ccccc2)cc(-c2ccccc2)c1 ; CC(C)(c1ccccc1)c1ccc2c(c1)B1c3cc(C(C)(C)c4ccccc4)ccc3N(c3ccc(-c4ccccc4)cc3)c3cccc(c31)N2c1ccc(-c2ccccc2)cc1]

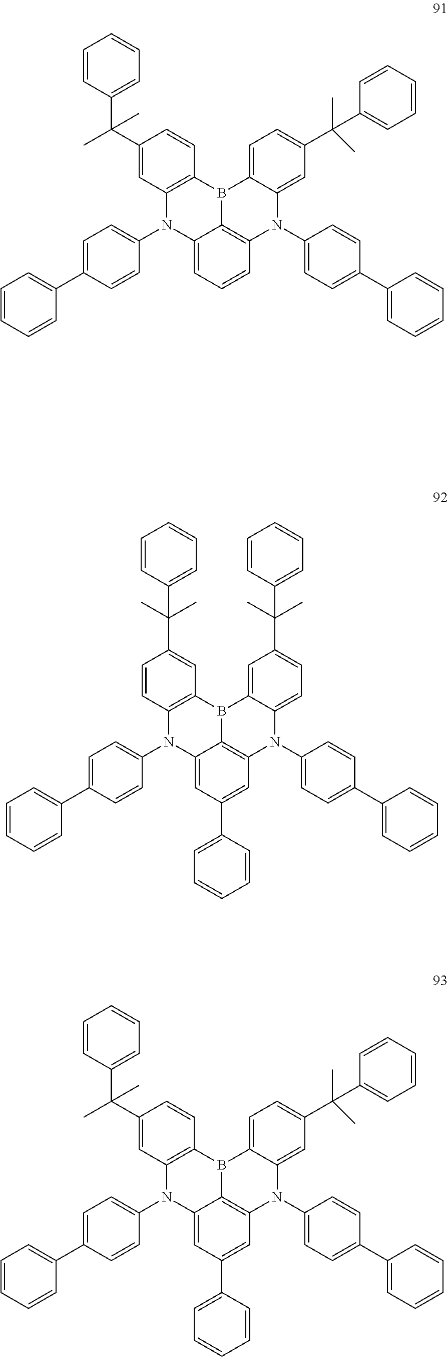 [SMILES: CC(C)(c1ccccc1)c1ccc2c(c1)N(c1ccc(-c3ccccc3)cc1)c1cccc3c1B2c1ccc(C(C)(C)c2ccccc2)cc1N3c1ccc(-c2ccccc2)cc1 ; CC(C)(c1ccccc1)c1ccc2c(c1)B1c3cc(C(C)(C)c4ccccc4)ccc3N(c3ccc(-c4ccccc4)cc3)c3cc(-c4ccccc4)cc(c31)N2c1ccc(-c2ccccc2)cc1 ; CC(C)(c1ccccc1)c1ccc2c(c1)N(c1ccc(-c3ccccc3)cc1)c1cc(-c3ccccc3)cc3c1B2c1ccc(C(C)(C)c2ccccc2)cc1N3c1ccc(-c2ccccc2)cc1]

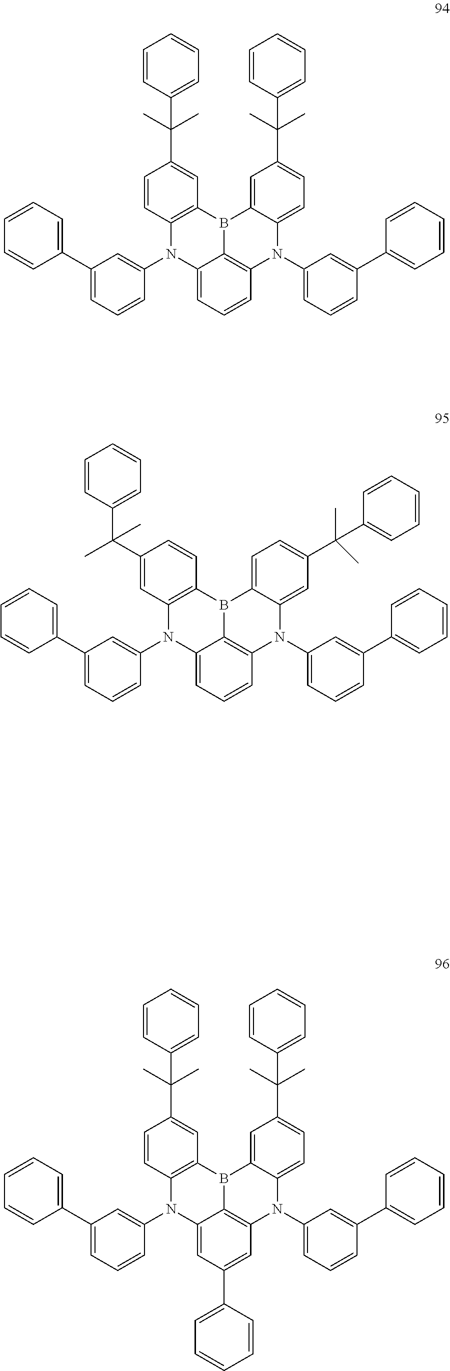 [SMILES: CC(C)(c1ccccc1)c1ccc2c(c1)B1c3cc(C(C)(C)c4ccccc4)ccc3N(c3cccc(-c4ccccc4)c3)c3cccc(c31)N2c1cccc(-c2ccccc2)c1 ; CC(C)(c1ccccc1)c1ccc2c(c1)N(c1cccc(-c3ccccc3)c1)c1cccc3c1B2c1ccc(C(C)(C)c2ccccc2)cc1N3c1cccc(-c2ccccc2)c1 ; CC(C)(c1ccccc1)c1ccc2c(c1)B1c3cc(C(C)(C)c4ccccc4)ccc3N(c3cccc(-c4ccccc4)c3)c3cc(-c4ccccc4)cc(c31)N2c1cccc(-c2ccccc2)c1]

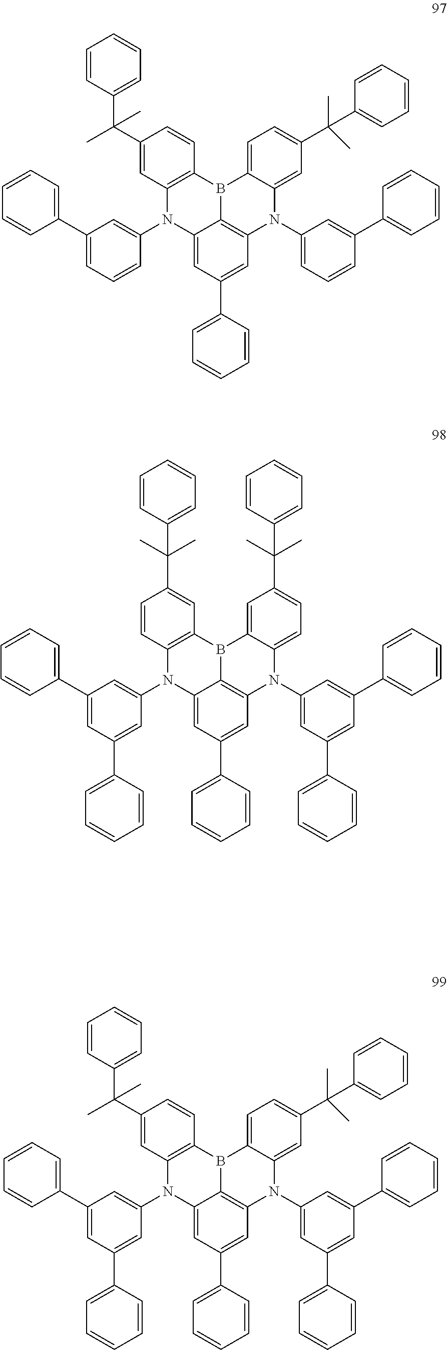 [SMILES: CC(C)(c1ccccc1)c1ccc2c(c1)N(c1cccc(-c3ccccc3)c1)c1cc(-c3ccccc3)cc3c1B2c1ccc(C(C)(C)c2ccccc2)cc1N3c1cccc(-c2ccccc2)c1 ; CC(C)(c1ccccc1)c1ccc2c(c1)B1c3cc(C(C)(C)c4ccccc4)ccc3N(c3cc(-c4ccccc4)cc(-c4ccccc4)c3)c3cc(-c4ccccc4)cc(c31)N2c1cc(-c2ccccc2)cc(-c2ccccc2)c1 ; CC(C)(c1ccccc1)c1ccc2c(c1)N(c1cc(-c3ccccc3)cc(-c3ccccc3)c1)c1cc(-c3ccccc3)cc3c1B2c1ccc(C(C)(C)c2ccccc2)cc1N3c1cc(-c2ccccc2)cc(-c2ccccc2)c1]

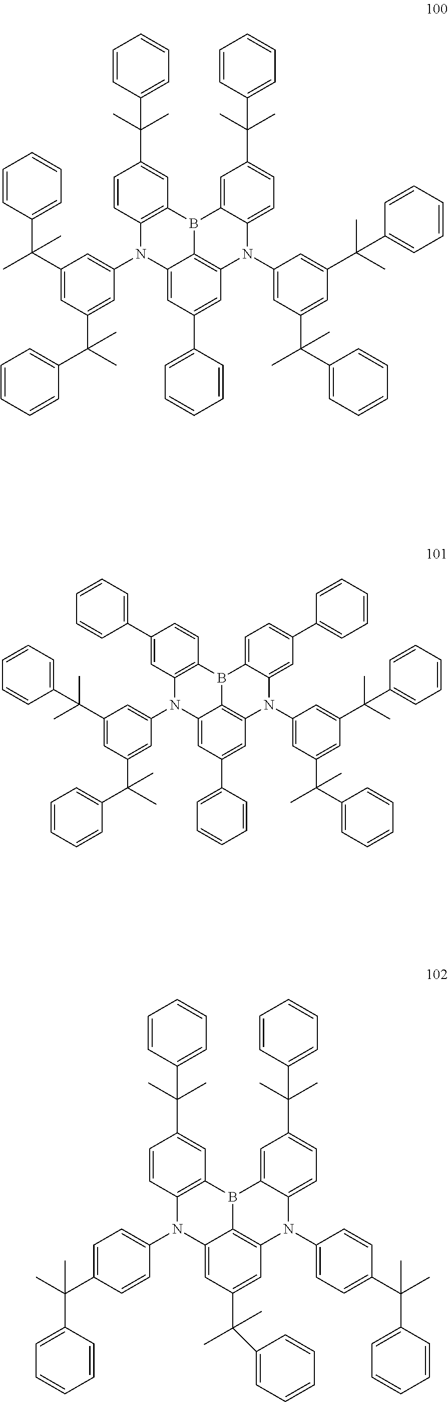 [SMILES: CC(C)(c1ccccc1)c1cc(N2c3ccc(C(C)(C)c4ccccc4)cc3B3c4cc(C(C)(C)c5ccccc5)ccc4N(c4cc(C(C)(C)c5ccccc5)cc(C(C)(C)c5ccccc5)c4)c4cc(-c5ccccc5)cc2c43)cc(C(C)(C)c2ccccc2)c1 ; CC(C)(c1ccccc1)c1cc(N2c3cc(-c4ccccc4)ccc3B3c4ccc(-c5ccccc5)cc4N(c4cc(C(C)(C)c5ccccc5)cc(C(C)(C)c5ccccc5)c4)c4cc(-c5ccccc5)cc2c43)cc(C(C)(C)c2ccccc2)c1 ; CC(C)(c1ccccc1)c1ccc(N2c3ccc(C(C)(C)c4ccccc4)cc3B3c4cc(C(C)(C)c5ccccc5)ccc4N(c4ccc(C(C)(C)c5ccccc5)cc4)c4cc(C(C)(C)c5ccccc5)cc2c43)cc1]

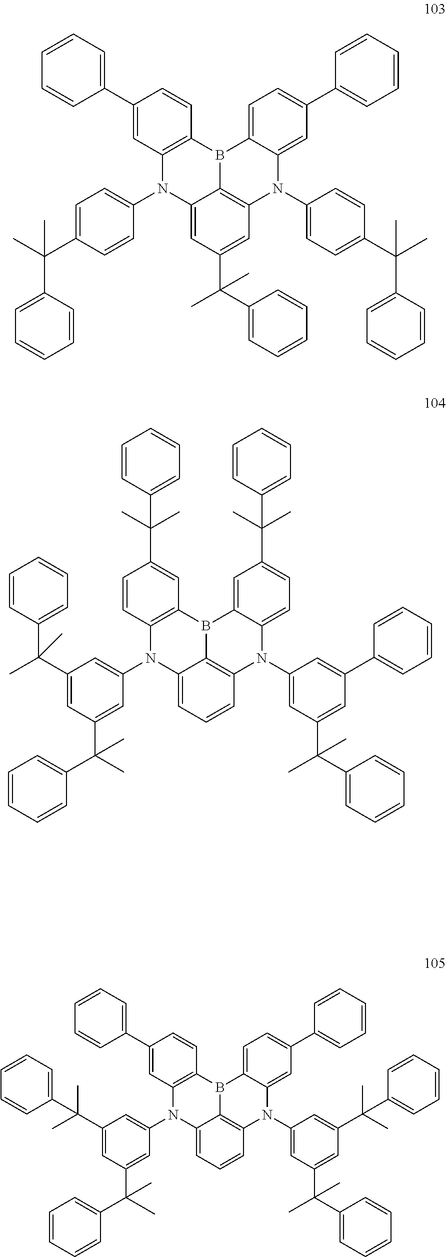 [SMILES: CC(C)(c1ccccc1)c1ccc(N2c3cc(-c4ccccc4)ccc3B3c4ccc(-c5ccccc5)cc4N(c4ccc(C(C)(C)c5ccccc5)cc4)c4cc(C(C)(C)c5ccccc5)cc2c43)cc1 ; CC(C)(c1ccccc1)c1cc(-c2ccccc2)cc(N2c3ccc(C(C)(C)c4ccccc4)cc3B3c4cc(C(C)(C)c5ccccc5)ccc4N(c4cc(C(C)(C)c5ccccc5)cc(C(C)(C)c5ccccc5)c4)c4cccc2c43)c1 ; CC(C)(c1ccccc1)c1cc(N2c3cc(-c4ccccc4)ccc3B3c4ccc(-c5ccccc5)cc4N(c4cc(C(C)(C)c5ccccc5)cc(C(C)(C)c5ccccc5)c4)c4cccc2c43)cc(C(C)(C)c2ccccc2)c1]

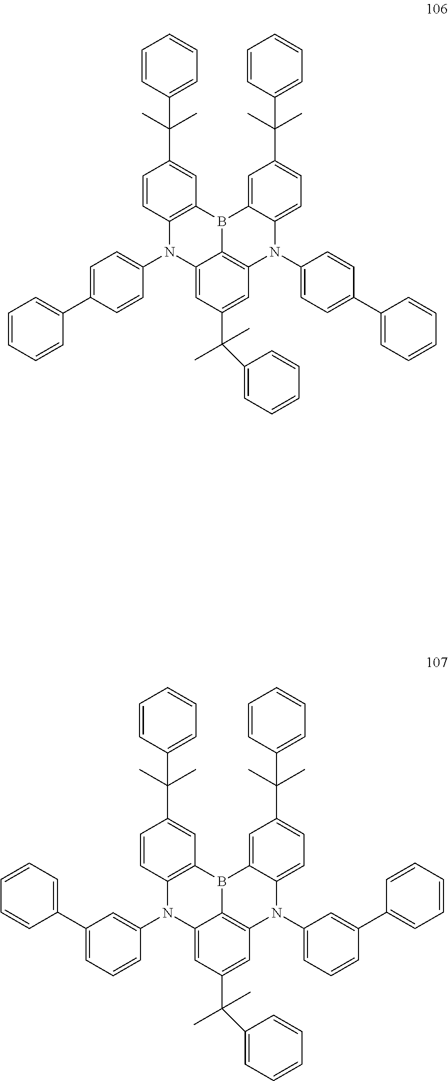 [SMILES: CC(C)(c1ccccc1)c1ccc2c(c1)B1c3cc(C(C)(C)c4ccccc4)ccc3N(c3ccc(-c4ccccc4)cc3)c3cc(C(C)(C)c4ccccc4)cc(c31)N2c1ccc(-c2ccccc2)cc1 ; CC(C)(c1ccccc1)c1ccc2c(c1)B1c3cc(C(C)(C)c4ccccc4)ccc3N(c3cccc(-c4ccccc4)c3)c3cc(C(C)(C)c4ccccc4)cc(c31)N2c1cccc(-c2ccccc2)c1]

Since the condensed ring core of the polycyclic compound represented by Formula 1 is substituted with at least one group represented by Formula 1-1, an organic light-emitting device including the polycyclic compound may have high luminescence efficiency and high color purity at the same time.

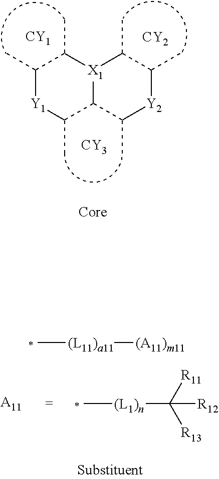

In the related art, a bulky alkyl group having a non-conjugated structure was introduced into the condensed ring core in order to improve efficiency among the luminescence characteristics of the core. However, as the energy difference between excited S₁ and excited T₁ increases and the energy overlap range decreases, the frequency of occurrence of reverse intersystem crossing decreases, and as a result, the efficiency decreases.

However, in the case of the compound represented by Formula 1, an arylalkyl group represented by Formula 1-1 wherein A is represented by Formula 1-2 and at least one of R₁₁ to R₁₃ is a substituted or unsubstituted C₆-C₆₀ aryl group, is introduced to a condensed ring core of the related art. Accordingly, the energy difference between excited S₁ and excited T₁ decreases and the energy overlap range increases, and thus, the reverse intersystem crossing from T₁ to S₁ easily occurs, and thus, the efficiency increases.

The highest occupied molecular orbital (HOMO) energy level, lowest unoccupied molecular orbital (LUMO) energy level, S₁ energy level, and T₁ energy level (in electron volts, eV) of some of the polycyclic compounds represented by Formula 1 were evaluated using the Gaussian 09 program with the molecular structure optimization obtained by B3LYP-based density functional theory (DFT), and results thereof are shown in Table 1.

TABLE 1

| | HOMO | LUMO | S₁ | T₁ |
|---|---|---|---|---|
| Compound No. | (eV) | (eV) | (eV) | (eV) |
| Compound 1 | −4.605 | −1.032 | 3.042 | 2.576 |
| Compound 2 | −4.904 | −1.234 | 3.146 | 2.660 |
| Compound 3 | −4.873 | −1.247 | 3.109 | 2.617 |
| Compound 4 | −4.799 | −1.191 | 3.087 | 2.609 |
| Compound 5 | −4.701 | −1.059 | 3.107 | 2.634 |
| Compound 6 | −4.673 | −1.070 | 3.075 | 2.594 |

From Table 1, it is confirmed that the polycyclic compound represented by Formula 1 has such electric characteristics that are suitable for use as a light-emitting dopant for an electronic device, for example, an organic light-emitting device.

Synthesis method of the polycyclic compound represented by Formula 1 may be recognized by those skilled in the art with reference to the following Synthesis Examples.

The polycyclic compound represented by Formula 1 is suitable for use in an organic layer of an organic light-emitting device, for example, for use as a dopant in an emission layer of the organic layer. Thus, another aspect provides an organic light-emitting device that includes: a first electrode; a second electrode; and an organic layer that is located between the first electrode and the second electrode and includes an emission layer, wherein the organic layer includes at least one polycyclic compound represented by Formula 1.

In one or more embodiments, the polycyclic compound may be included in the emission layer.

In one or more embodiments, the emission layer may further include a host, and the polycyclic compound may be a light-emitting dopant. In this regard, the amount of host in the emission layer may be greater than the amount of the polycyclic compound.

In one or more embodiments, the emission layer may further include a host and a light-emitting dopant, and the polycyclic compound may be a sensitizer. In this regard, the amount of host in the emission layer may be greater than the total amount of the light-emitting dopant and the sensitizer. The host will be described in detail.

The organic light-emitting device includes an organic layer including the polycyclic compound represented by Formula 1 as described above. Accordingly, such an organic light-emitting device may have low driving voltage, high efficiency, high power, high quantum efficiency, long lifespan, a low roll-off ratio, and excellent color purity.

A polycyclic compound represented by Formula 1 may be used between a pair of electrodes in an organic light-emitting device. In one or more embodiments, polycyclic compound represented by Formula 1 may be included in the emission layer. In this regard, the polycyclic compound acts as a light-emitting dopant or a sensitizer, and the emission layer may further include a host (that is, the amount of polycyclic compound represented by Formula 1 may be smaller than the amount of the host). The emission layer may emit blue light, for example, blue light having the maximum emission wavelength of 450 nm or more (for example, 450 nm or more and 500 nm or less).

The expression “(an organic layer) includes at least one polycyclic compound” as used herein may include a case in which “(an organic layer) includes identical polycyclic compounds represented by Formula 1” and a case in which “(an organic layer) includes two or more different polycyclic compounds represented by Formula 1”.

For example, the organic layer may include, as the polycyclic compound, only Compound 1. In this embodiment, Compound 1 may be included in the emission layer of the organic light-emitting device. In one or more embodiments, the organic layer may include, as the polycyclic compound, Compound 1 and Compound 2. In this regard, Compound 1 and Compound 2 may exist in an identical layer (for example, Compound 1 and Compound 2 all may exist in an emission layer).

The first electrode may be an anode, which is a hole injection electrode, and the second electrode may be a cathode, which is an electron injection electrode; or the first electrode may be a cathode, which is an electron injection electrode, and the second electrode may be an anode, which is a hole injection electrode.

In one or more embodiments, in the organic light-emitting device, the first electrode is an anode, and the second electrode is a cathode, and the organic layer may further include a hole transport region between the first electrode and the emission layer and an electron transport region between the emission layer and the second electrode, and the hole transport region may include a hole injection layer, a hole transport layer, an electron blocking layer, a buffer layer, or any combination thereof, and the electron transport region may include a hole blocking layer, an electron transport layer, an electron injection layer, or any combination thereof.

The term “organic layer” used herein refers to a single layer and/or a plurality of layers between the first electrode and the second electrode of the organic light-emitting device. The “organic layer” may include, in addition to an organic compound, an organometallic complex including metal.

The term “sensitize” refers to a compound that is included in an organic layer (for example, an emission layer) and may deliver excitation energy to a light-emitting dopant compound.

### OLED System

The organic light-emitting device according to one or more embodiments may include an emission layer including a host and a light-emitting dopant. The amount of the host in the emission layer may be greater than the amount of the light-emitting dopant.

The host may include one or more compounds that is a fluorescent host or a phosphorescent host which will be described later. When the host includes two or more mixed hosts, the mixed host may form an exciplex host.

The host will be described in detail later.

The light-emitting dopant may include the polycyclic compound represented by Formula 1.

An organic light-emitting device according to another embodiment of the present disclosure may include an emission layer including a host, a sensitizer, and a light-emitting dopant. The amount of the host in the emission layer may be greater than the total amount of the light-emitting dopant and the sensitizer.

The host will be described in detail later.

At least one of the sensitizer and the light-emitting dopant may include the polycyclic compound represented by Formula 1.

In one or more embodiments, the sensitizer may include the polycyclic compound represented by Formula 1. In one or more embodiments, the sensitizer may include a compound having an energy relationship suitable to transfer the excited singlet energy and/or excited triplet energy to the light-emitting dopant, in relation to the light-emitting dopant.

In one or more embodiments, the sensitizer may include the polycyclic compound represented by Formula 1, and the light-emitting dopant may be a phosphorescent dopant.

The singlet excitons and triplet excitons of the polycyclic compound may be respectively delivered to the excited singlet and triplet energy levels of the phosphorescent dopant through Forster Resonance Energy Transfer (FRET) and a Dexter Energy Transfer (DET) mechanism, and the triplet excitons of the phosphorescent dopant exhibit phosphorescent emission.

In one or more embodiments, the sensitizer may include the polycyclic compound represented by Formula 1, and the light-emitting dopant may include a thermally activate delayed fluorescence (TADF) compound.

The singlet excitons and triplet excitons of the polycyclic compound may be respectively delivered to the excited singlet and excited triplet energy levels of the TADF compound through a FRET mechanism and a DET mechanism, and triplet excitons in the TADF compound may be converted to singlet excitons by reverse inter system crossing (RISC), and accumulated singlet excitons may be sequentially transitioned to a ground state, exhibiting fluorescence.

In one or more embodiments, the sensitizer includes the polycyclic compound represented by Formula 1, wherein the polycyclic compound may be a TADF compound, and the light-emitting dopant may include a phosphorescent dopant or a TADF compound.

In the TADF polycyclic compound, triplet excitons within the polycyclic compound are converted into singlet excitons by RISC, and at the same time, energy transfer to the light-emitting dopant by FRET and DET mechanisms may occur.

Without wishing to be bound to theory, since the sensitizer contains the polycyclic compound represented by Formula 1, the triplet-triplet annihilation of the triplet excitons may be suppressed and the luminescence efficiency of the light-emitting dopant may be improved.

In one or more embodiments, the light-emitting dopant includes the polycyclic compound represented by Formula 1, and the sensitizer may include a TADF compound or an organometallic compound. However, embodiments of the present disclosure are not limited thereto. Any compound that can transmit excitons to a polycyclic compound may be included.

The excitons formed in the sensitizer are transferred to a light-emitting dopant compound through a DET mechanism or a FRET mechanism, and the excitons energy transferred to the light-emitting dopant compound may be transitioned to a ground state, emitting light.

In this regard, the excitons of the sensitizer may be formed by the FRET mechanism from the host compound, or by the delivery of excitons generated from the host by the DET mechanism.

In one or more embodiments, the sensitizer may be a TADF compound.

In addition, the sensitizer may satisfy Equation 1:

ΔE_{ST}≤0.3 eV Equation 1

In this regard, ΔE_{ST} refers to the energy difference between the lowest excited singlet (S₁) and the lowest excited triplet (T₁).

The TADF compound includes singlet excitons and triplet excitons, and energy of triplet excitons can be transferred to singlet excitons by RISC, and the singlet excitons accumulated in the singlet of the sensitizer may be energy-transitioned to the polycyclic compound by FRET and/or DET.

In one or more embodiments, the sensitizer may be an organometallic compound. In one or more embodiments, the sensitizer may be an organometallic compound including Pt as a central metal, but embodiments of the present disclosure are not limited thereto.

The organometallic compound includes singlet excitons and triplet excitons, and in the case of triplet excitons, energy can be transferred to the excited triplet energy of the polycyclic compound by the DET mechanism.

The organometallic compound may satisfy Equation 1 above, and when Equation 1 is satisfied, excitons may be delivered to the excited singlet and excited triplet energy levels of the polycyclic compound by a mechanism similar to the mechanism applied to the TADF compound, that is, the FRET and/or DET mechanism.

In one or more embodiments, the excited singlet energy level and the excited triplet energy level of the sensitizer may be lower than the excited singlet energy and excited triplet energy of the host. Therefore, excited singlet and triplet energy transfer from the host to the sensitizer may easily occur.

In one or more embodiments, the sensitizer and the light-emitting dopant may each independently have the polycyclic compound represented by Formula 1.

As a result, energy transfer between the sensitizer and the light-emitting dopant is facilitated by FRET and DET mechanisms, and it is easy to manufacture a high-efficiency organic light-emitting device by suppressing triplet-triplet annihilation.

In general, it is known that since triplet excitons stay long in an excited state, they influence the decrease in the lifespan of organic light-emitting devices. However, according to the present disclosure, due to the use of the polycyclic compound, the time during which the sensitizer stays in the triplet excitons is reduced, and thus, the lifespan of an organic light-emitting device including the same may be prolonged.

In one or more embodiments, the polycyclic compound is a material capable of emitting fluorescent light. An emission layer emitting the fluorescent light is clearly distinguished from an emission layer of the related art that emits phosphorescent light.

In one or more embodiments, the polycyclic compound may emit TADF light.

The excited singlet and excited triplet energy levels of the polycyclic compound may be lower than the excited singlet and excited triplet energy levels of the host compound described later. Accordingly, singlet excitons and/or triplet excitons are easily transitioned from the host compound to the polycyclic compound.

The polycyclic compound may receive singlet excitons and/or triplet excitons from the sensitizer.

In one or more embodiments, when the sensitizer is a TADF compound, the excited singlet energy level of the polycyclic compound is lower than the excited singlet energy level of the sensitizer, and the polycyclic compound may receive singlet excitons from the excited singlet of the sensitizer by the FRET and/or DET mechanism.

In one or more embodiments, when the sensitizer is an organometallic compound, the excited triplet energy level of the polycydic compound is lower than the excited triplet level of the sensitizer, and the polycydic compound may receive triplet excitons from the sensitizer by DET mechanism.

When the sensitizer is a TADF compound or an organometallic compound, the polycyclic compound may further receive singlet excitons and/or triplet excitons from the host, and the triplet excitons received from the host may be transitioned to singlet energy of the polycyclic compound by RISC.

Due to this mechanism, triplet-triplet annihilation may be suppressed by reducing the time during which excitons stay in the excited triplet energy of the polycyclic compound, and high-efficiency fluorescent light emission is realized through the transition of multiple singlet excitons to the ground state.

The amount of the sensitizer in the emission layer may be from about 5 wt % to about 50 wt % on the basis of weight of the emission layer. Within these ranges, it is possible to achieve effective energy transfer in the emission layer, and accordingly, an organic light-emitting device having high efficiency and long lifespan can be obtained.

In one or more embodiments, the host, the polycyclic compound, and the sensitizer may satisfy Equation 2:

[T₁(H)/S₁(H)]≥[T₁(S)/S₁(S)]≥[T₁(PC)/S₁(PC)] Equation 2

wherein, in Equation 2,

T₁(H) is a lowest excited triplet energy level of the host;

S₁(H) is a lowest excited singlet energy level of the host;

T₁(PC) is a lowest excited triplet energy level of the polycyclic compound;

S₁(PC) is a lowest excited singlet energy level of the polycyclic compound;

T₁(S) is a lowest excited triplet energy level of the sensitizer; and

S₁(S) is a lowest excited singlet energy level of the sensitizer.

When the host, the polycyclic compound, and the sensitizer further satisfy Equation 2, triplet excitons may be effectively transferred from the host to the polycyclic compound, thereby obtaining an organic light-emitting device with improved efficiency.

A thickness of the emission layer may be in a range of about 100 Å to about 1,000 Å, for example, about 200 Å to about 600 Å. When the thickness of the emission layer is within these ranges, excellent light-emission characteristics may be obtained without a substantial increase in driving voltage.

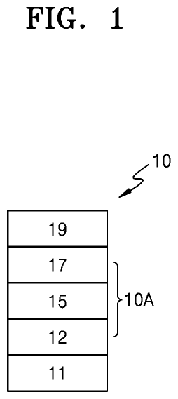

### Description of FIG. 1

FIG. 1 is a schematic cross-sectional view of an organic light-emitting device 10 according to one or more embodiments. Hereinafter, the structure of an organic light-emitting device according to an exemplary embodiment of the present disclosure and an exemplary method of manufacturing an organic light-emitting device according to one or more embodiments of the present disclosure will be described in connection with FIG. 1.

The organic light-emitting device 10 of FIG. 1 includes a first electrode 11, a second electrode 19 facing the first electrode 11, and an organic layer 10A located between the first electrode 11 and the second electrode 19.

The organic layer 10A includes an emission layer 15, a hole transport region 12 may be located between the first electrode 11 and the emission layer 15, and an electron transport region 17 may be located between the emission layer 15 and the second electrodes 19.

A substrate may be additionally located under the first electrode 11 or above the second electrode 19. For use as the substrate, any substrate that is used in organic light-emitting devices available in the art may be used, and the substrate may be a glass substrate or a transparent plastic substrate, each having excellent mechanical strength, thermal stability, transparency, surface smoothness, ease of handling, and water resistance.

### First Electrode 11

In one or more embodiments, the first electrode 11 may be formed by depositing or sputtering a material for forming the first electrode 11 on the substrate. The first electrode 11 may be an anode. The material for forming the first electrode 11 may be selected from materials with a high work function to facilitate hole injection. The first electrode 11 may be a reflective electrode, a semi-transmissive electrode, or a transmissive electrode. The material for forming the first electrode 11 may be indium tin oxide (ITO), indium zinc oxide (IZO), tin oxide (SnO₂), or zinc oxide (ZnO). In one or more embodiments, the material for forming the first electrode 11 may be metal, such as magnesium (Mg), aluminum (Al), aluminum-lithium (Al—Li), calcium (Ca), magnesium-indium (Mg—In), or magnesium-silver (Mg—Ag).

The first electrode 11 may have a single-layered structure or a multi-layered structure including two or more layers. For example, the first electrode 11 may have a three-layered structure of ITO/Ag/ITO, but the structure of the first electrode 11 is not limited thereto.

The organic layer 10A is located on the first electrode 11.

The organic layer 10A may include a hole transport region 12, an emission layer 15, and an electron transport region 17.

### Hole Transport Region 12

The hole transport region 12 may be located between the first electrode 11 and the emission layer 15 of the organic light-emitting device 10.

The hole transport region 12 may have a single-layered structure or a multi-layered structure.

For example, the hole transport region 12 may have a hole injection layer, a hole transport layer, a hole injection layer/hole transport layer structure, a hole injection layer/first hole transport layer/second hole transport layer structure, a hole transport layer/middle layer structure, a hole injection layer/hole transport layer/middle layer structure, a hole transport layer/electron blocking layer structure, or a hole injection layer/hole transport layer/electron blocking layer structure, but embodiments of the present disclosure are not limited thereto.

The hole transport region 12 may include any compound having hole transport properties.

For example, the hole transport region 12 may include an amine compound.

In one or more embodiments, the hole transport region 1 may include at least one amine compound represented by one Formula 201 to Formula 205, but embodiments of the present disclosure are not limited thereto:

wherein, in Formulae 201 to 205,

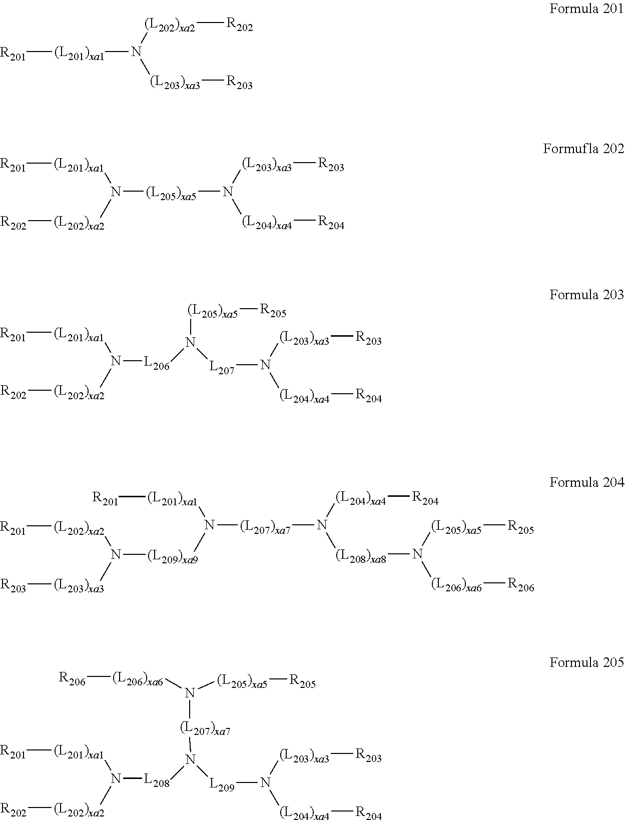

L₂₀₁ to L₂₀₉ may each independently *-be O—*′, *—S—*′, a substituted or unsubstituted C₅-C₆₀ carbocyclic group, or a substituted or unsubstituted C₁-C₆₀ heterocyclic group,

xa1 to xa9 may each independently be an integer from 0 to 5, and

R₂₀₁ to R₂₀₆ may each independently be a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₇-C₆₀ alkyl aryl group, a substituted or unsubstituted C₆-C₆₀ aryloxy group, a substituted or unsubstituted C₆-C₆₀ arylthio group, a substituted or unsubstituted C₁-C₆₀ heteroaryl group, substituted or unsubstituted C₁-C₆₀ heteroaryloxy group, a substituted or unsubstituted C₁-C₆₀ heteroarylthio group, a substituted or unsubstituted C₂-C₆₀ heteroarylalkyl group, a substituted or unsubstituted monovalent non-aromatic condensed polycyclic group, or a substituted or unsubstituted monovalent non-aromatic condensed heteropolycyclic group, wherein two adjacent groups of R₂₀₁ to R₂₀₆ may optionally be linked to each other via a single bond, a dimethyl-methylene group, or a diphenyl-methylene group.

For example, in one or more embodiments,

L₂₀₁ to L₂₀₉ may each independently be a benzene group, a heptalene group, an indene group, a naphthalene group, an azulene group, an indacene group, an acenaphthylene group, a fluorene group, a spiro-bifluorene group, a benzofluorene group, a dibenzofluorene group, a phenalene group, a phenanthrene group, an anthracene group, a fluoranthene group, a triphenylene group, a pyrene group, a chrysene group, a naphthacene group, a picene group, a perylene group, a pentacene group, a hexacene group, a rubicene group, a coronene group, an ovalene group, a pyrrole group, an isoindole group, an indole group, a furan group, a thiophene group, a benzofuran group, a benzothiophene group, a benzocarbazole group, a dibenzocarbazole group, a dibenzofuran group, a dibenzothiophene group, a dibenzothiophene sulfone group, a carbazole group, a dibenzosilole group, an indenocarbazole group, an indolocarbazole group, a benzofurocarbazole group, a benzothienocarbazole group, or a triindolobenzene group, each unsubstituted or substituted with deuterium, a C₁-C₁₀ alkyl group, a C₁-C₁₀ alkoxy group, a phenyl group, a naphthyl group, a fluorenyl group, a carbazolyl group, a dibenzofuranyl group, a dibenzothiophenyl group, a triphenylenyl group, a biphenyl group, a terphenyl group, a quaterphenyl group, or —Si(Q₁₁)(Q₁₂)(Q₁₃),

xa1 to xa9 may each independently be 0, 1, or 2,

R₂₀₁ to R₂₀₆ may each independently be a phenyl group, a biphenyl group, a terphenyl group, a pentalenyl group, an indenyl group, a naphthyl group, an azulenyl group, a heptalenyl group, an indacenyl group, an acenaphthyl group, a fluorenyl group, a spiro-bifluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, a pyridinyl group, an indeno carbazolyl group, an indolocarbazolyl group, a benzofurocarbazolyl group, or a benzothienocarbazolyl group, each unsubstituted or substituted with at least one of deuterium, —F, —Cl, —Br, —I, a hydroxyl group, a cyano group, a nitro group, an amidino group, a hydrazine group, a hydrazone group, a C₁-C₂₀ alkyl group, a C₁-C₂₀ alkoxy group, a cyclopentyl group, a cyclohexyl group, a cycloheptyl group, a cyclopentenyl group, a cyclohexenyl group, a phenyl group, a biphenyl group, a terphenyl group, a phenyl group substituted with a C₁-C₁₀ alkyl group, a phenyl group substituted with —F, a pentalenyl group, an indenyl group, a naphthyl group, an azulenyl group, a heptalenyl group, an indacenyl group, an acenaphthyl group, a fluorenyl group, a spiro-bifluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, a pyridinyl group, —Si(Q₃₁)(Q₃₂)(Q₃₃), or —N(Q₃₁)(Q₃₂), or

Q₁₁ to Q₁₃ and Q₃₁ to Q₃₃ may each independently be a C₁-C₁₀ alkyl group, a C₁-C₁₀ alkoxy group, a phenyl group, a biphenyl group, a terphenyl group, or a naphthyl group.

In one or more embodiments, the amine compound of the hole transport region 12 may include a carbazole-containing amine compound.

In one or more embodiments, the hole transport region 12 may include a carbazole-containing amine compound and a carbazole-free amine compound.

The carbazole-containing amine compound may be, for example, a compound represented by Formula 201 including a carbazole group and further including at least one of a dibenzofuran group, a dibenzothiophene group, a fluorene group, a spiro-bifluorene group, an indenocarbazole group, an indolocarbazole group, a benzofurocarbazole group, or a benzothienocarbazole group.

The carbazole-free amine compound may be, for example, a compound represented by Formula 201 that does not include a carbazole group and that includes at least one of a dibenzofuran group, a dibenzothiophene group, a fluorene group, a spiro-bifluorene group, an indenocarbazole group, an indolocarbazole group, a benzofurocarbazole group, or a benzothienocarbazole group.

In one or more embodiments, the hole transport region 12 may include at least one compound represented by Formulae 201 or 202.

In one or more embodiments, the hole transport region 12 may include at least one of the compounds represented by Formulae 201-1, 202-1 and 201-2, but embodiments of the present disclosure are not limited thereto:

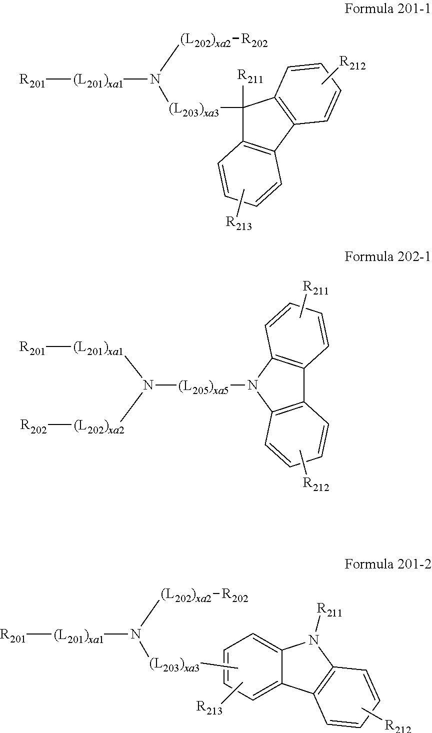

In Formulae 201-1, 202-1, and 201-2, L₂₀₁ to L₂₀₃, L₂₀₅, xa1 to xa3, xa5, R₂₀₁ and R₂₀₂ are the same as described herein, and R₂₁₁ to R₂₁₃ are each independently hydrogen, deuterium, —F, —Cl, —Br, —I, a hydroxyl group, a cyano group, a nitro group, an amidino group, a hydrazine group, a hydrazone group, a C₁-C₂₀ alkyl group, a C₁-C₂₀ alkoxy group, a phenyl group, a biphenyl group, a terphenyl group, a phenyl group substituted with a C₁-C₁₀ alkyl group, a phenyl group substituted with —F, a naphthyl group, a fluorenyl group, a spiro-bifluorenyl group, a dimethyffluorenyl group, a diphenylfluorenyl group, a triphenylenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, or a pyridinyl group.

For example, the hole transport region 12 may include at least one of Compounds HT1 to HT39, but embodiments of the present disclosure are not limited thereto.

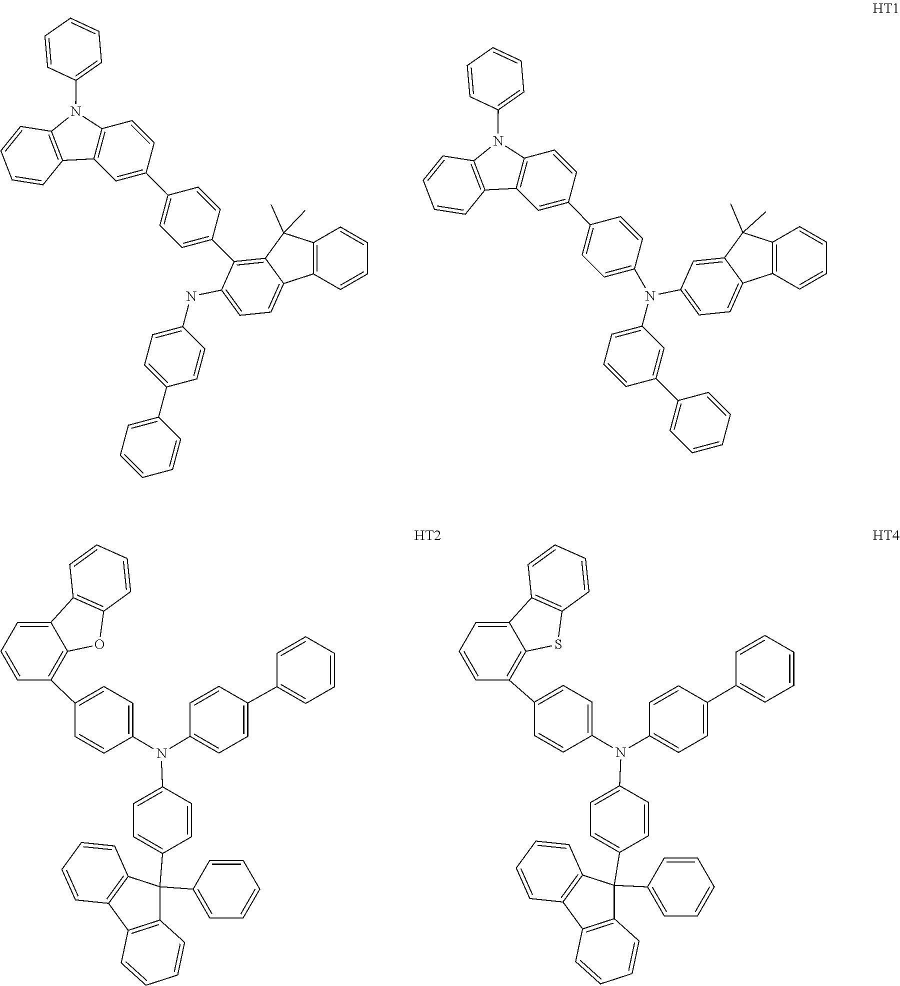 [SMILES: CC1(C)c2ccccc2-c2ccc(Nc3ccc(-c4ccccc4)cc3)c(-c3ccc(-c4ccc5c(c4)c4ccccc4n5-c4ccccc4)cc3)c21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; c1ccc(-c2ccc(N(c3ccc(-c4cccc5c4oc4ccccc45)cc3)c3ccc(C4(c5ccccc5)c5ccccc5-c5ccccc54)cc3)cc2)cc1 ; c1ccc(-c2ccc(N(c3ccc(-c4cccc5c4sc4ccccc45)cc3)c3ccc(C4(c5ccccc5)c5ccccc5-c5ccccc54)cc3)cc2)cc1]

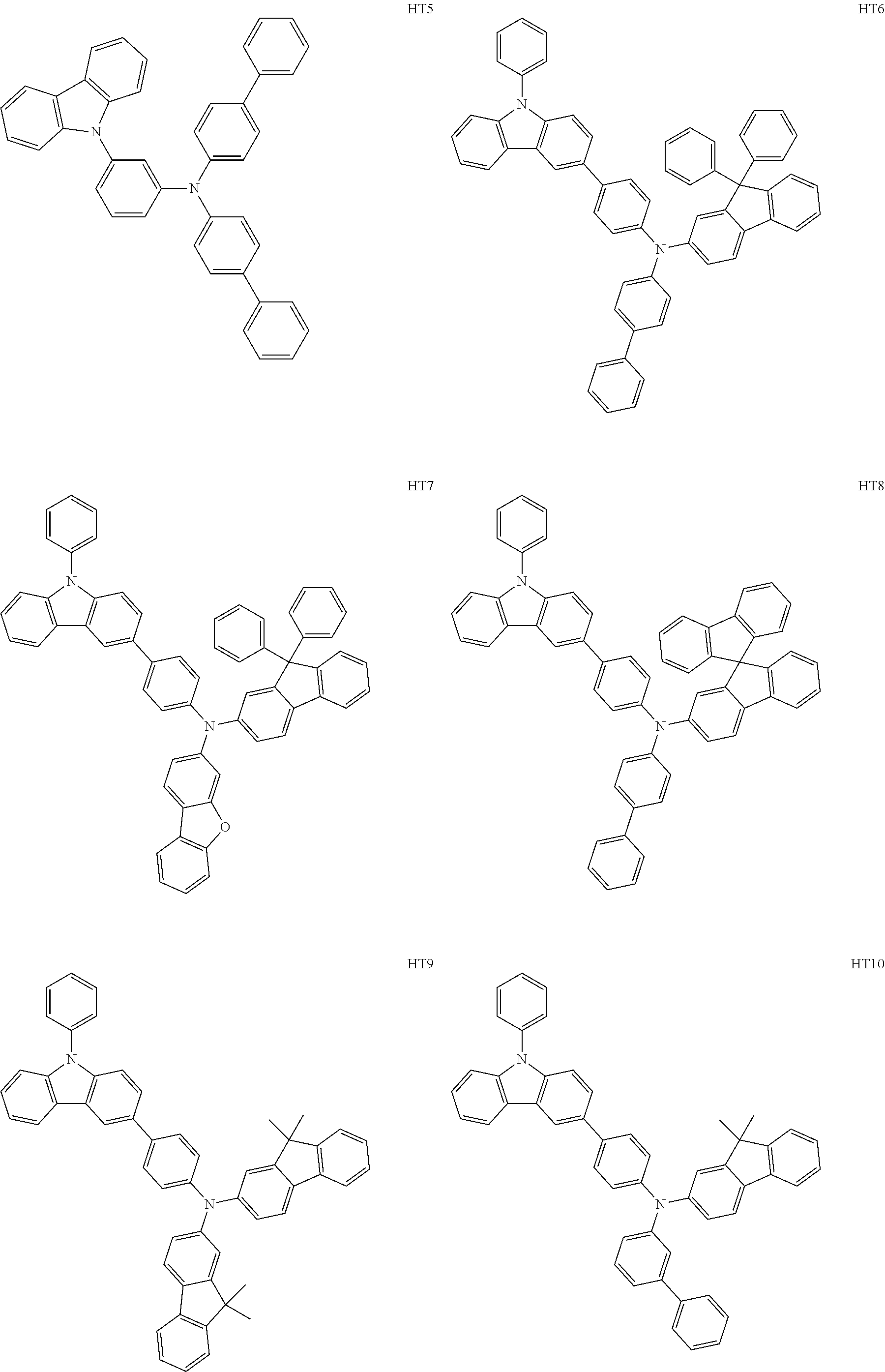

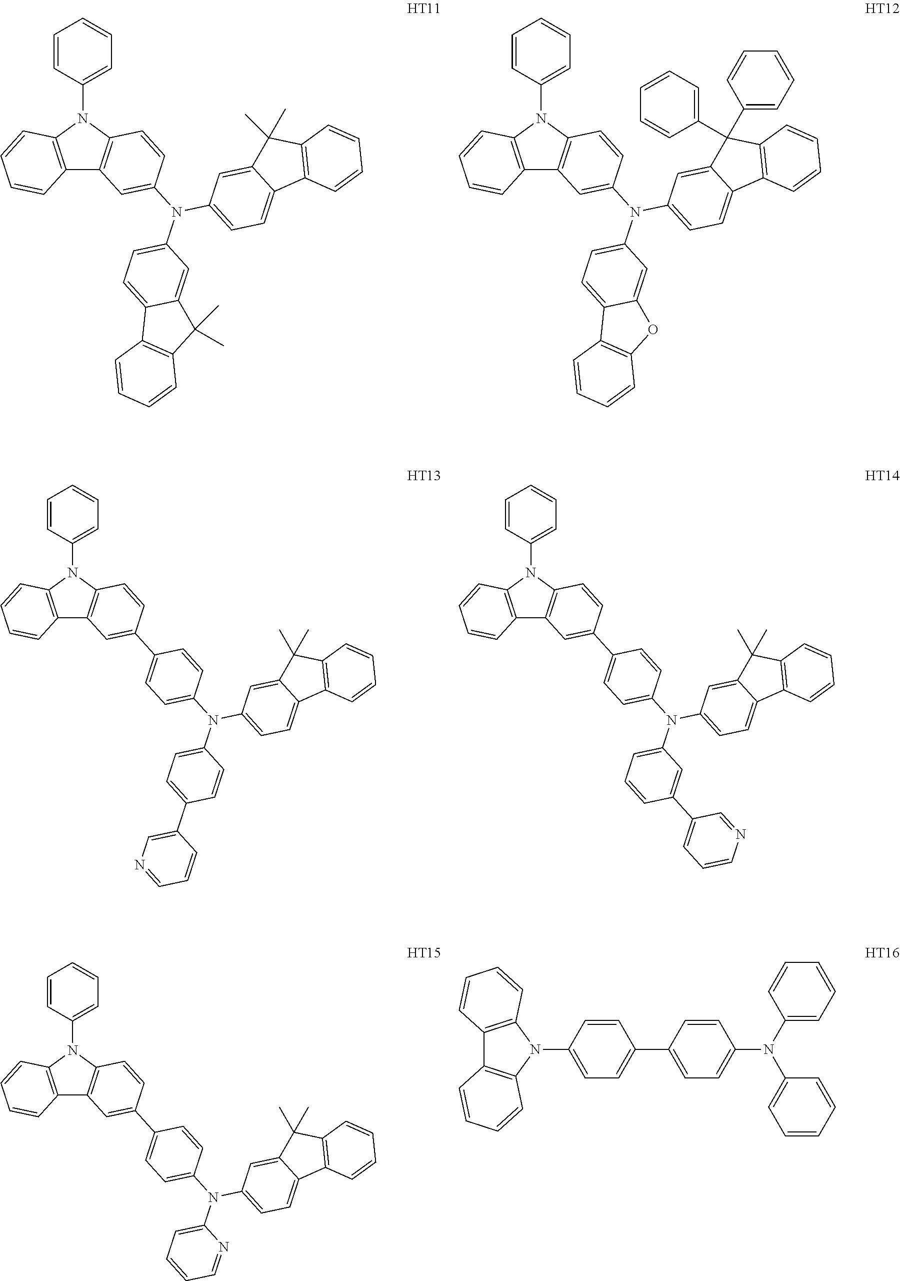

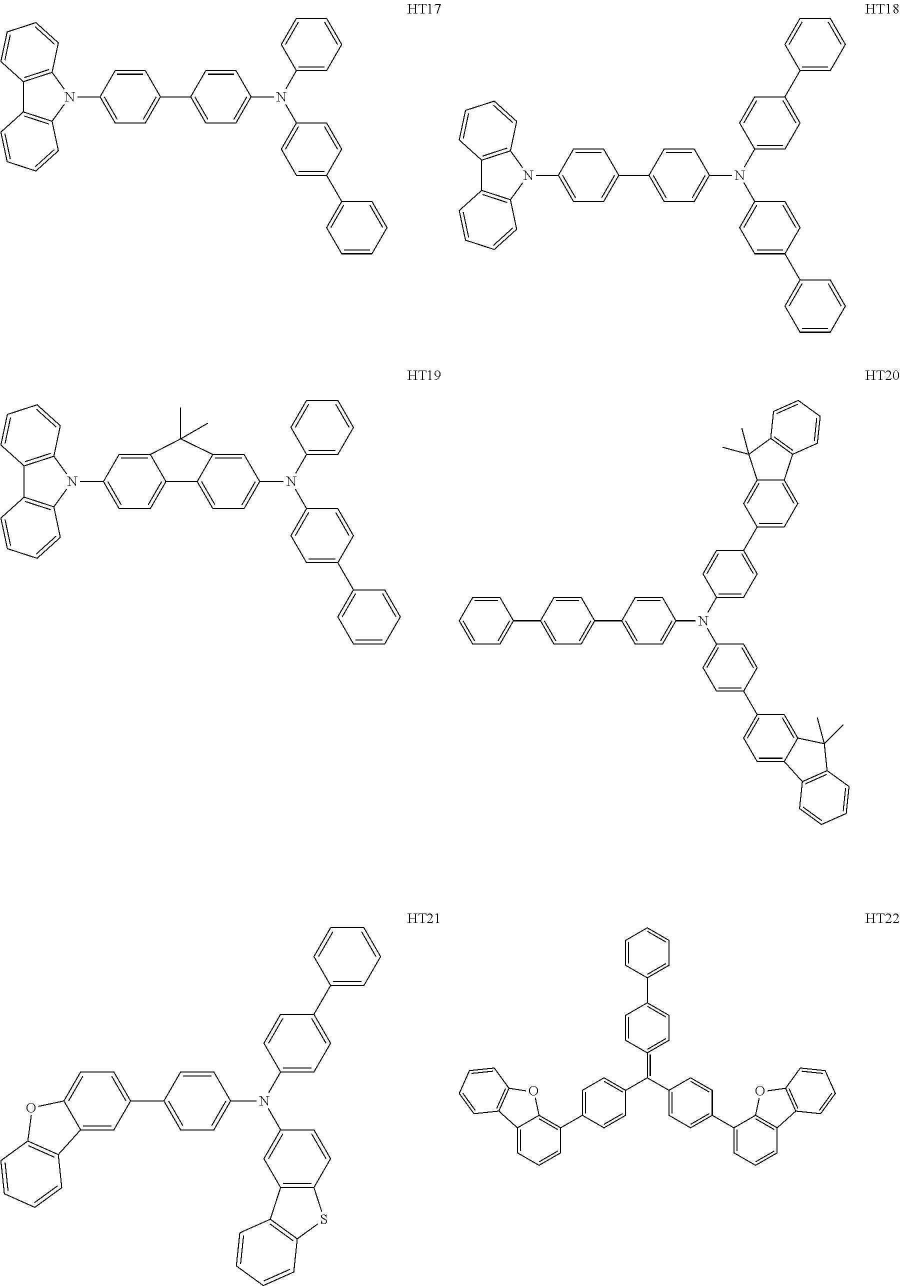

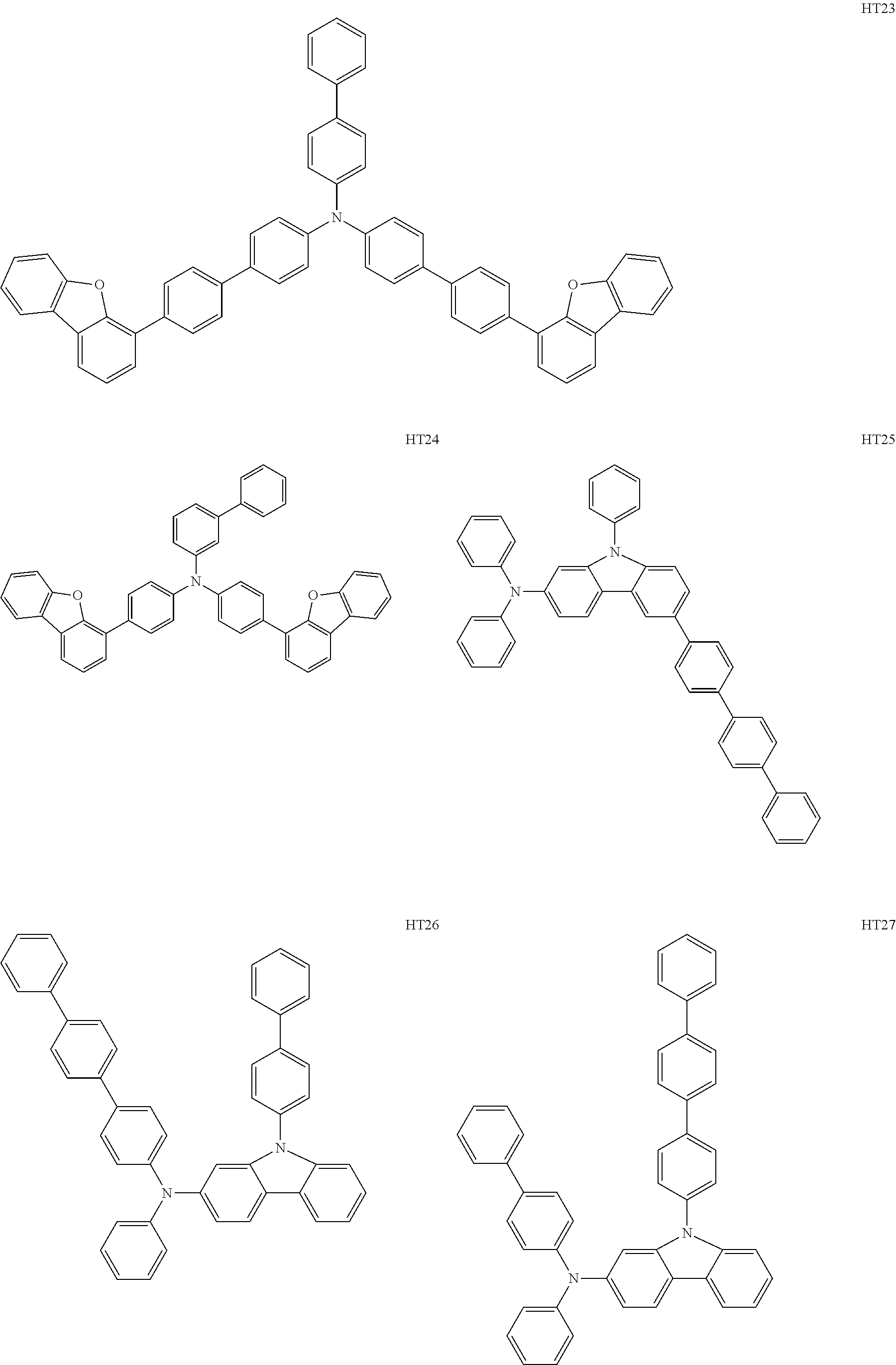 [SMILES: c1ccc(-c2ccc(N(c3ccc(-c4ccc(-c5cccc6c5oc5ccccc56)cc4)cc3)c3ccc(-c4ccc(-c5cccc6c5oc5ccccc56)cc4)cc3)cc2)cc1 ; c1ccc(-c2cccc(N(c3ccc(-c4cccc5c4oc4ccccc45)cc3)c3ccc(-c4cccc5c4oc4ccccc45)cc3)c2)cc1 ; c1ccc(-c2ccc(-c3ccc(-c4ccc5c(c4)c4ccc(N(c6ccccc6)c6ccccc6)cc4n5-c4ccccc4)cc3)cc2)cc1 ; c1ccc(-c2ccc(-c3ccc(N(c4ccccc4)c4ccc5c6ccccc6n(-c6ccc(-c7ccccc7)cc6)c5c4)cc3)cc2)cc1 ; c1ccc(-c2ccc(-c3ccc(-n4c5ccccc5c5ccc(N(c6ccccc6)c6ccc(-c7ccccc7)cc6)cc54)cc3)cc2)cc1]

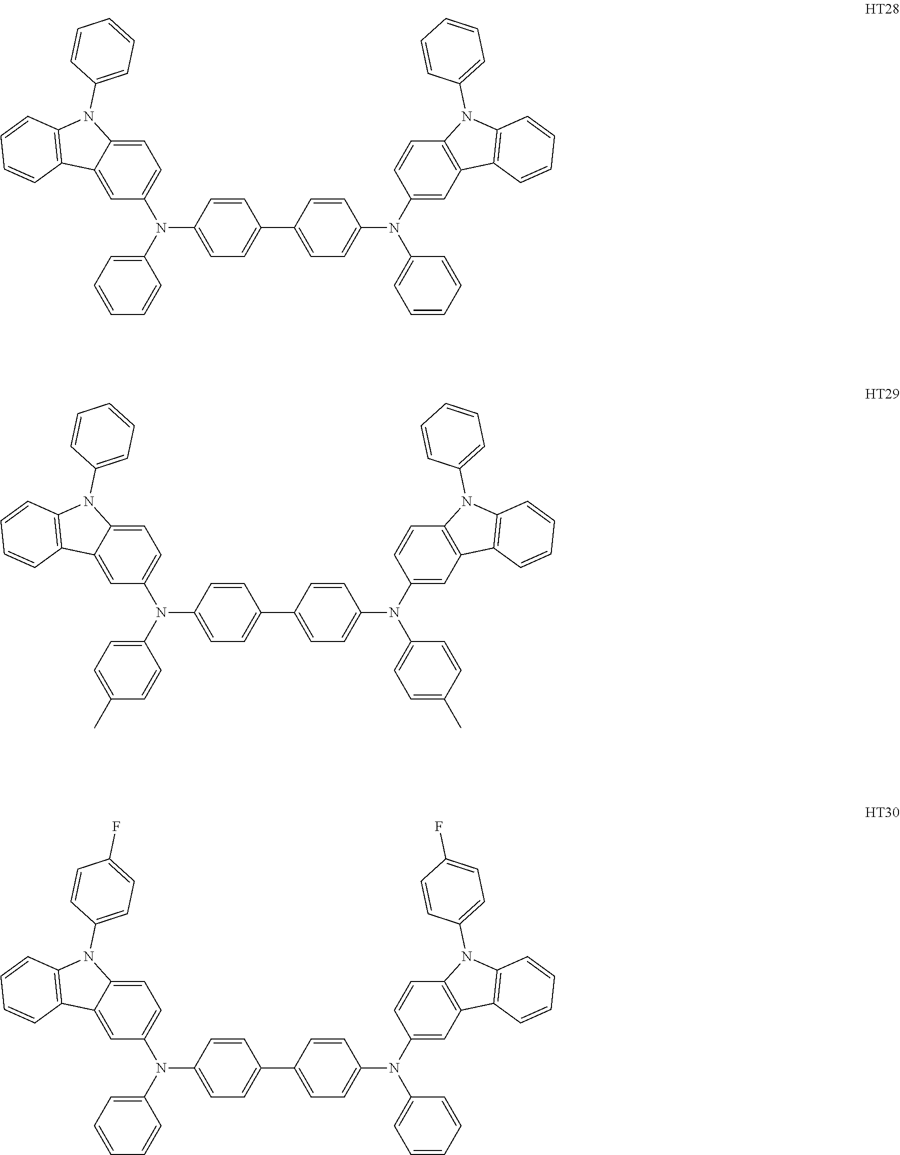 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; Cc1ccc(N(c2ccc(-c3ccc(N(c4ccc(C)cc4)c4ccc5c(c4)c4ccccc4n5-c4ccccc4)cc3)cc2)c2ccc3c(c2)c2ccccc2n3-c2ccccc2)cc1 ; Fc1ccc(-n2c3ccccc3c3cc(N(c4ccccc4)c4ccc(-c5ccc(N(c6ccccc6)c6ccc7c(c6)c6ccccc6n7-c6ccc(F)cc6)cc5)cc4)ccc32)cc1]

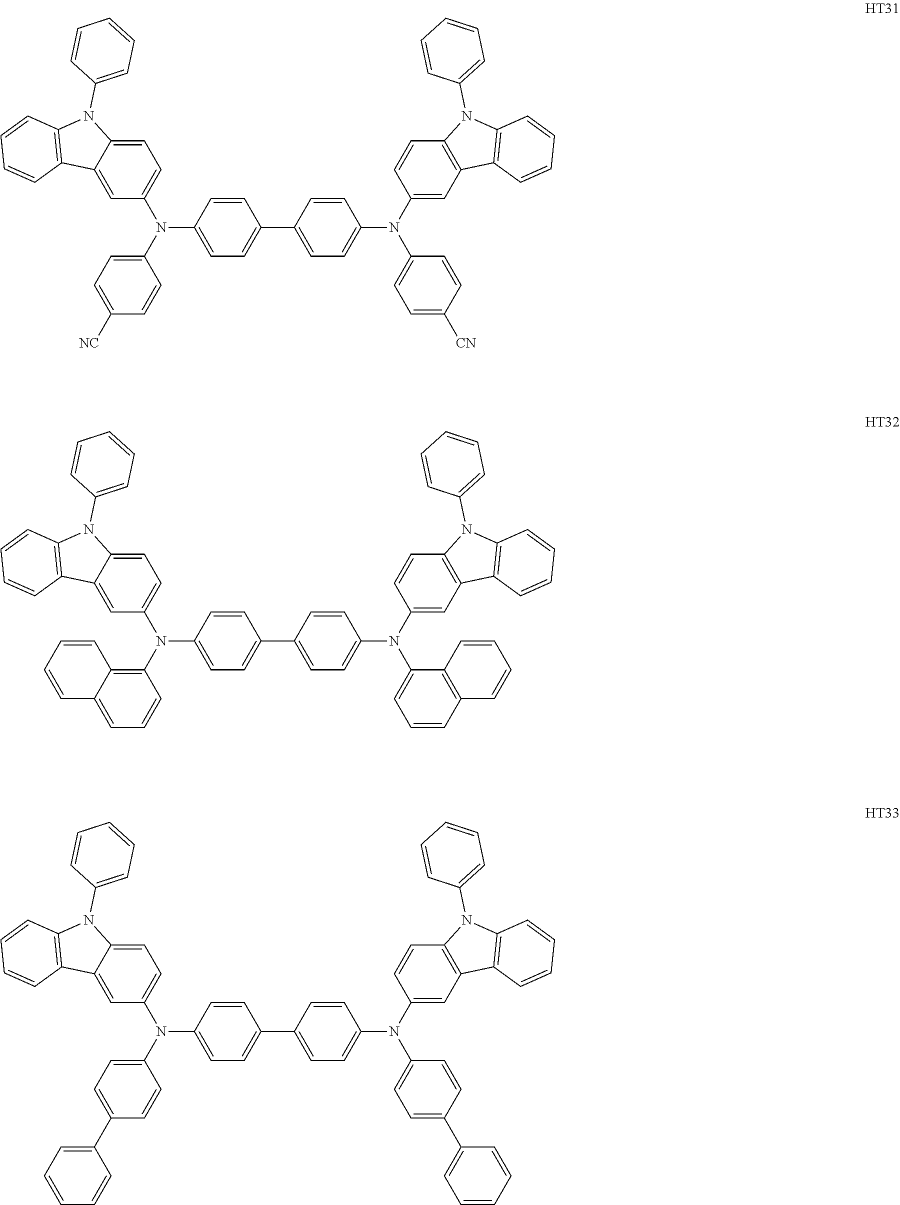 [SMILES: N#Cc1ccc(N(c2ccc(-c3ccc(N(c4ccc(C#N)cc4)c4ccc5c(c4)c4ccccc4n5-c4ccccc4)cc3)cc2)c2ccc3c(c2)c2ccccc2n3-c2ccccc2)cc1 ; c1ccc(-n2c3ccccc3c3cc(N(c4ccc(-c5ccc(N(c6ccc7c(c6)c6ccccc6n7-c6ccccc6)c6cccc7ccccc67)cc5)cc4)c4cccc5ccccc45)ccc32)cc1 ; c1ccc(-c2ccc(N(c3ccc(-c4ccc(N(c5ccc(-c6ccccc6)cc5)c5ccc6c(c5)c5ccccc5n6-c5ccccc5)cc4)cc3)c3ccc4c(c3)c3ccccc3n4-c3ccccc3)cc2)cc1]

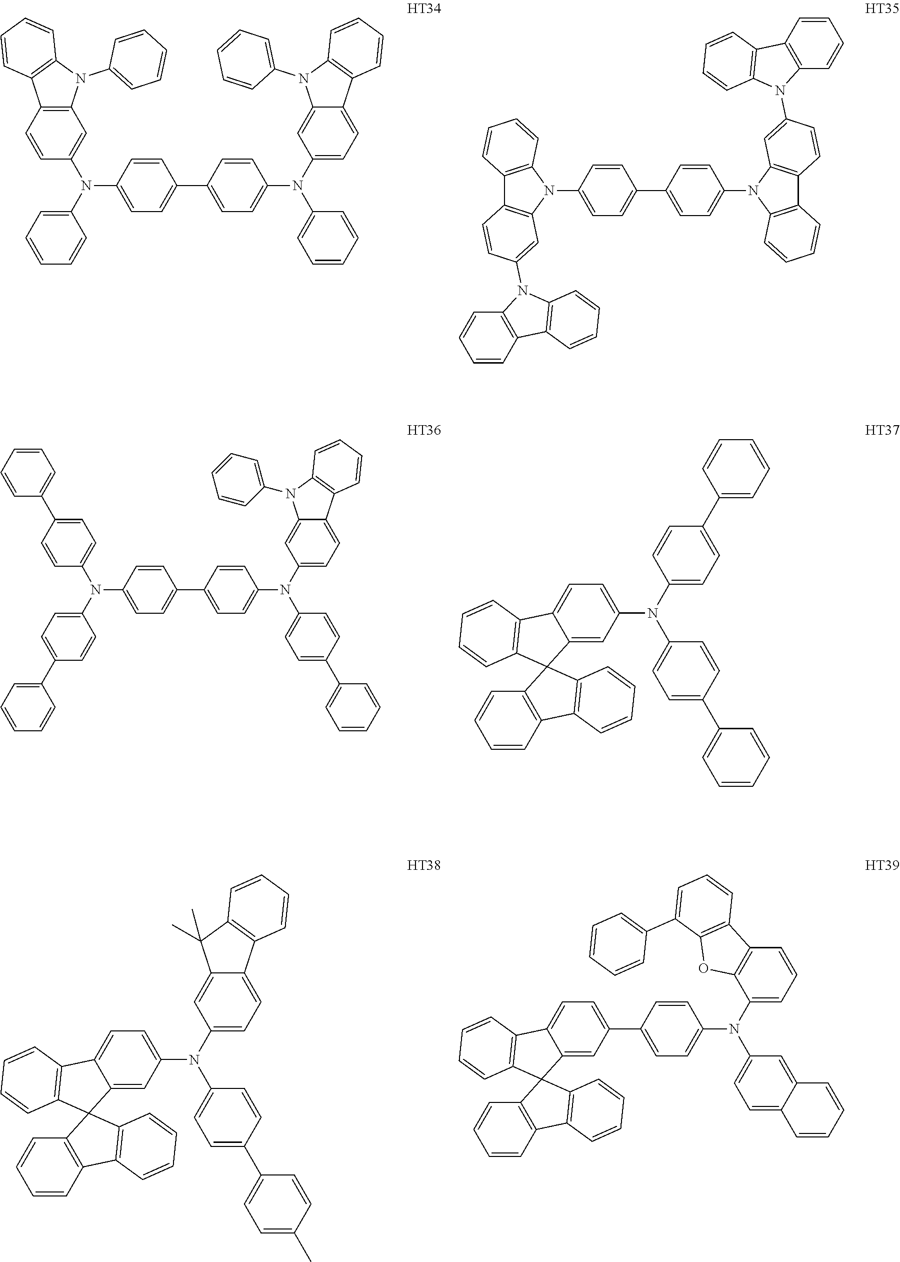

In one or more embodiments, hole transport region 12 of the organic light-emitting device 10 may further include a p-dopant. When the hole transport region 12 further includes a p-dopant, the hole transport region 12 may have a matrix, for example, at least one of compounds represented by Formulae 201 to 205, and a p-dopant included in the matrix. The p-dopant may be uniformly or non-uniformly doped in the hole transport region 12.

In one or more embodiments, the LUMO energy level of the p-dopant may be −3.5 electron volts (eV) or less.

The p-dopant may include at least one of a quinone derivative, a metal oxide, or a cyano group-containing compound, but embodiments of the present disclosure are not limited thereto.

In one or more embodiments, the p-dopant may include at least one of:

a quinone derivative, such as tetracyanoquinodimethane (TCNQ),2,3,5,6-tetrafluoro-7,7,8,8-tetracyanoquinodimethane (F4-TCNQ), or F6-TCNNQ;

a metal oxide, such as tungsten oxide or molybdenum oxide;

1,4,5,8,9,12-hexaazatriphenylene-hexacarbonitrile (HAT-CN); or

a compound represented by Formula 221 below, but embodiments of the present disclosure are not limited thereto:

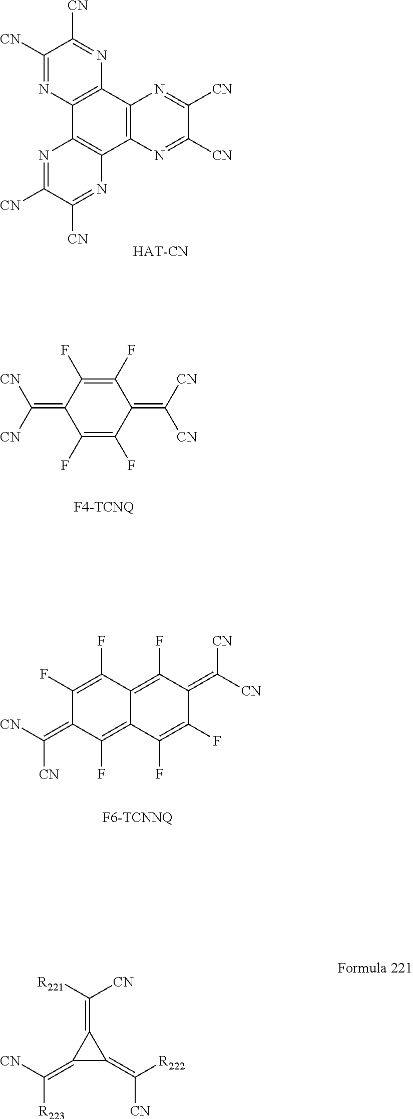

In Formula 221,

R₂₂₁ to R₂₂₃ may each independently be a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₁-C₆₀ aryl group, a substituted or unsubstituted C₇-C₆₀ alkyl aryl group, a substituted or unsubstituted C₇-C₆₀ aryl alkyl group, a substituted or unsubstituted C₁-C₆₀ heteroaryl group, a substituted or unsubstituted C₂-C₆₀ alkyl heteroaryl group, a substituted or unsubstituted C₂-C₆₀ heteroaryl alkyl group, a substituted or unsubstituted monovalent non-aromatic condensed polycyclic group, or a substituted or unsubstituted monovalent non-aromatic condensed heteropolycyclic group, and at least one of R₂₂₁ to R₂₂₃ may have at least one substituent that is a cyano group, —F, —Cl, —Br, —I, a C₁-C₂₀ alkyl group substituted with —F, a C₁-C₂₀ alkyl group substituted with —Cl, a C₁-C₂₀ alkyl group substituted with —Br, or a C₁-C₂₀ alkyl group substituted with —I.

The hole transport region 12 may have a thickness of about 100 Å to about 10000 Å, for example, about 400 Å to about 2000 Å, and the emission layer 15 may have a thickness of about 100 Å to about 3000 Å, for example, about 300 Å to about 1000 Å. When the thickness of each of the hole transport region 12 and the emission layer 15 is within these ranges described above, satisfactory hole transportation characteristics and/or luminescent characteristics may be obtained without a substantial increase in driving voltage.

### Emission Layer 15

The emission layer may further include a host, and the light-emitting dopant may include the polycyclic compound represented by Formula 1. The host may include no metal atoms.

In one or more embodiments, the host may include one kind of host. When the host includes one host, the one host may be a bipolar host, an electron transport host, or a hole transport host, which will be described later.

In one or more embodiments, the host may include a mixture of two or more different hosts. For example, the host may be a mixture of an electron transport host and a hole transport host, a mixture of two types of electron transport hosts different from each other, or a mixture of two types of hole transport hosts different from each other. The electron transport host and the hole transport host may be understood by referring to the related description to be presented later.

In one or more embodiments, the host may include an electron transport host including at least one electron transport moiety and a hole transport host that is free of an electron transport moiety.

The electron transport moiety used herein may be a cyano group, a π electron-deficient nitrogen-containing cyclic group, or a group represented by one of the following Formulae:

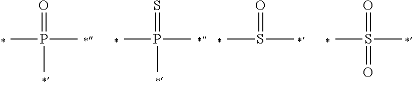

In the formulae, *, *′, and *″ are each binding sites to neighboring atoms.

In one or more embodiments, the electron transport host of the emission layer may include at least one of a cyano group and a π electron-deficient nitrogen-containing cyclic group.

In one or more embodiments, the electron transport host in the emission layer may include at least one cyano group.

In one or more embodiments, the electron transport host in the emission layer may include at least one cyano group and at least one π electron deficient nitrogen-containing cyclic group.

In one or more embodiments, the host may include an electron transport host and a hole transport host, wherein the electron transport host may include at least one π electron-deficient nitrogen-free cyclic group and at least one electron transport moiety, and the hole transport host may include at least one π electron-deficient nitrogen-free cyclic group and may not include an electron transport moiety.

The term “π electron-deficient nitrogen-containing cyclic group” used herein refers to a cyclic group having at least one *—N═*′ moiety, and for example, may be an imidazole group, a pyrazole group, a thiazole group, an isothiazole group, an oxazole group, an isoxazole group, a pyridine group, a pyrazine group, a pyridazine group, a pyrimidine group, an indazole group, a purine group, a quinoline group, an isoquinoline group, a benzoquinoline group, a phthalazine group, a naphthyridine group, a quinoxaline group, a quinazoline group, a cinnoline group, a phenanthridine group, an acridine group, a phenanthroline group, a phenazine group, a benzimidazole group, an isobenzothiazole group, a benzoxazole group, an isobenzoxazole group, a triazole group, a tetrazole group, an oxadiazole group, a triazine group, a thiadiazole group, an imidazopyridine group, an imidazopyrimidine group, or an azacarbazole group; or a condensed cyclic group in which two or more π electron-deficient nitrogen-containing cyclic groups are condensed with each other.

Meanwhile, the π electron-deficient nitrogen-free cyclic group may be a benzene group, a heptalene group, an indene group, a naphthalene group, an azulene group, an indacene group, acenaphthylene group, a fluorene group, a spiro-bifluorene group, a benzofluorene group, a dibenzofluorene group, a phenalene group, a phenanthrene group, an anthracene group, a fluoranthene group, a triphenylene group, a pyrene group, a chrysene group, a naphthacene group, a picene group, a perylene group, a pentacene group, a hexacene group, a rubicene group, a coronene group, an ovalene group, a pyrrole group, an isoindole group, an indole group, a furan group, a thiophene group, a benzofuran group, a benzothiophene group, a benzocarbazole group, a dibenzocarbazole group, a dibenzofuran group, a dibenzothiophene group, a dibenzothiophene sulfone group, a carbazole group, a dibenzosilole group, an indenocarbazole group, an indolocarbazole group, a benzofurocarbazole group, a benzothienocarbazole group, a triindolobenzene group; or a condensed cyclic group of two or more π electron-deficient nitrogen-free cyclic groups, but embodiments of the present disclosure are not limited thereto.

In one or more embodiments, the electron transport host may be a compound represented by Formula E-1, and

the hole transport host may be a compound represented by Formula H-1, but embodiments of the present disclosure are not limited thereto:

[Ar₃₀₁]_{xb11}-[(L₃₀₁)_{xb1}-R₃₀₁]_{xb21} Formula E-1

wherein, in Formula E-1,

Ar₃₀₁ may be a substituted or unsubstituted C₅-C₆₀ carbocyclic group or a substituted or unsubstituted C₁-C₆₀ heterocyclic group.

xb11 may be 1, 2, or 3,

L₃₀₁ may each independently be a single bond, a group represented by one of the following formula, a substituted or unsubstituted C₅-C₆₀ carbocyclic group, or a substituted or unsubstituted C₁-C₆₀ heterocyclic group, and *, *′ and *″ in the following formulae are each a binding site to a neighboring atom,

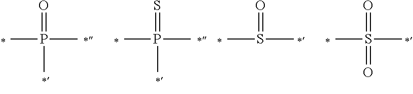

xb1 may be an integer from 1 to 5,

R₃₀₁ may be hydrogen, deuterium, —F, —Cl, —Br, —I, a hydroxyl group, a cyano group, a nitro group, an amidino group, a hydrazine group, a hydrazone group, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₇-C₆₀ alkyl aryl group, a substituted or unsubstituted C₆-C₆₀ aryloxy group, a substituted or unsubstituted C₆-C₆₀ arylthio group, a substituted or unsubstituted C₇-C₆₀ aryl alkyl group, a substituted or unsubstituted C₁-C₆₀ heteroaryl group, a substituted or unsubstituted C₁-C₆₀ heteroaryloxy group, a substituted or unsubstituted C₁-C₆₀ heteroarylthio group, a substituted or unsubstituted C₂-C₆₀ heteroarylalkyl group, a substituted or unsubstituted monovalent non-aromatic condensed polycyclic group, a substituted or unsubstituted monovalent non-aromatic condensed heteropolycyclic group, —Si(Q₃₀₁)(Q₃₀₂)(Q₃₀₃), —N(Q₃₀₁)(Q₃₀₂), —B(Q₃₀₁)(Q₃₀₂), —C(═O)(Q₃₀₁). —S(═O)₂(Q₃₀₁), —S(═O)(Q₃₀₁), —P(═O)(Q₃₀₁)(Q₃₀₂), or —P(═S)(Q₃₀₁)(Q₃₀₂),

xb21 may be an integer from 1 to 5,

Q₃₀₁ to Q₃₀₃ may each independently be a C₁-C₁₀ alkyl group, a C₁-C₁₀ alkoxy group, a phenyl group, a biphenyl group, a terphenyl group, or a naphthyl group, and

at least one of Condition 1 to Condition 3 may be satisfied:

### Condition 1

Ar₃₀₁, L₃₀₁, and R₃₀₁ in Formula E-1 may each independently include a π electron-deficient nitrogen-containing cyclic group

### Condition 2

L₃₀₁ in Formula E-1 is a group represented by one of the following groups:

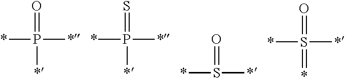

### Condition 3

R₃₀₁ in Formula E-1 may be a cyano group, —S(═O)₂(Q₃₀₁), —S(═O)(Q₃₀₁), —P(═O)(Q₃₀₁)(Q₃₀₂), or —P(═S)(Q₃₀₁)(Q₃₀₂),

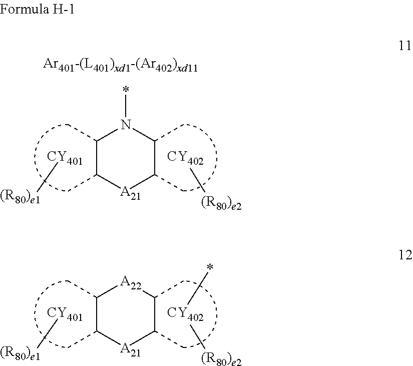

wherein, in Formulae H-1, 11, and 12,

L₄₀₁ may be:

a single bond; or

a benzene group, a heptalene group, an indene group, a naphthalene group, an azulene group, an indacene group, acenaphthylene group, a fluorene group, a spiro-bifluorene group, a benzofluorene group, a dibenzofluorene group, a phenalene group, a phenanthrene group, an anthracene group, a fluoranthene group, a triphenylene group, a pyrene group, a chrysene group, a naphthacene group, a picene group, a perylene group, a pentacene group, a hexacene group, a rubicene group, a coronene group, an ovalene group, a pyrrole group, an isoindole group, an indole group, a furan group, a thiophene group, a benzofuran group, a benzothiophene group, a benzocarbazole group, a dibenzocarbazole group, a dibenzofuran group, a dibenzothiophene group, a dibenzothiophene sulfone group, a carbazole group, a dibenzosilole group, an indenocarbazole group, an indolocarbazole group, a benzofurocarbazole group, a benzothienocarbazole group, or a triindolobenzene group, each unsubstituted or substituted with at least one of deuterium, a C₁-C₁₀ alkyl group, a C₁-C₁₀ alkoxy group, a phenyl group, a naphthyl group, a fluorenyl group, a carbazolyl group, a dibenzofuranyl group, a dibenzothiophenyl group, a triphenylenyl group, a biphenyl group, a terphenyl group, a quaterphenyl group, or —Si(Q₄₀₁)(Q₄₀₂)(Q₄₀₃);

xd1 may be an integer from 1 to 10, wherein when xd1 is 2 or more, two or more of L₄₀₁(s) may be identical to or different from each other,

Ar₄₀₁ may be a group represented by one of Formulae 11 or 12.

Ar₄₀₂ may be:

a group represented by one of Formula 11 or 12, a phenyl group, a naphthyl group, a fluorenyl group, a carbazolyl group, a dibenzofuranyl group, a dibenzothiophenyl group, a biphenyl group, a terphenyl group, or a triphenylenyl group; or

a phenyl group, a naphthyl group, a fluorenyl group, a carbazolyl group, a dibenzofuranyl group, a dibenzothiophenyl group, a biphenyl group, a terphenyl group, and a triphenylenyl group, each substituted with at least one of deuterium, a hydroxyl group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a phenyl group, a naphthyl group, a fluorenyl group, a carbazolyl group, a dibenzofuranyl group, a dibenzothiophenyl group, a biphenyl group, a terphenyl group, or a triphenylenyl group;

CY₄₀₁, and CY₄₀₂ may each independently be a benzene group, a naphthalene group, a fluorene group, a carbazole group, a benzocarbazole group, an indolocarbazole group, a dibenzofuran group, a dibenzothiophene group, a dibenzosilole group, a benzonaphthofuran group, a benzonaphthothiophene group, or a benzonaphthosilole group,

xd11 may be an integer from 1 to 10, wherein when xd11 is 2 or more, two or more of Ar₄₀₂(s) may be identical to or different from each other,

A₂₁ may be a single bond, O, S, N(R₅₁), C(R₅₁)(R₅₂), or Si(R₅₁)(R₅₂),

A₂₂ may be a single bond, O, S, N(R₅₃), C(R₅₃)(R₅₄), or Si(R₅₃)(R₅₄),

at least one of A₂₁ and A₂₂ in Formula 12 may not be a single bond,

R₅₁ to R₅₄, R₆₀, and R₇₀ may each independently be:

hydrogen, deuterium, a hydroxyl group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, or a C₁-C₂₀ alkoxy group;

a C₁-C₂₀ alkyl group and a C₁-C₂₀ alkoxy group, each substituted with at least one of deuterium, a hydroxyl group, an amino group, an amidino group, a hydrazine group, a hydrazone group, a carboxylic acid group or a salt thereof, a sulfonic acid group or a salt thereof, a phosphoric acid group or a salt thereof, a phenyl group, a naphthyl group, a fluorenyl group, a carbazolyl group, a dibenzofuranyl group, or a dibenzothiophenyl group;

a π electron-deficient nitrogen-free cyclic group (for example, a phenyl group, a naphthyl group, a fluorenyl group, a carbazolyl group, a dibenzofuranyl group, a dibenzothiophenyl group, a biphenyl group, a terphenyl group, or a triphenylenyl group);

a π electron-deficient nitrogen-free cyclic group (for example, a phenyl group, a naphthyl group, a fluorenyl group, a carbazolyl group, a dibenzofuranyl group, a dibenzothiophenyl group, a biphenyl group, a terphenyl group, and a triphenylenyl group), each substituted with at least one of deuterium, a hydroxyl group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a phenyl group, a naphthyl group, a fluorenyl group, a carbazolyl group, a dibenzofuranyl group, a dibenzothiophenyl group, or a biphenyl group; or

—Si(Q₄₀₄)(Q₄₀₅)(Q₄₀₆),

e1 and e2 may each independently be an integer from 0 to 10,

Q₄₀₁ to Q₄₀₆ may each independently be hydrogen, deuterium, a hydroxyl group, an amino group, an amidino group, a hydrazine group, a hydrazone group, a carboxylic acid or a salt thereof, a sulfonic acid or a salt thereof, a phosphoric acid or a salt thereof, a phenyl group, a naphthyl group, a fluorenyl group, a carbazolyl group, a dibenzofuranyl group, a dibenzothiophenyl group, a biphenyl group, a terphenyl group, or a triphenylenyl group, and

* indicates a binding site to an adjacent atom.

In one or more embodiments, at least one of A₂₁ and A₂₂ in Formula 12 is not a single bond.

In one or more embodiments. Ar₃₀₁ and L₃₀₁ in Formula E-1 may each independently be a benzene group, a naphthalene group, a fluorene group, a spiro-bifluorene group, a benzofluorene group, a dibenzofluorene group, a phenalene group, a phenanthrene group, an anthracene group, a fluoranthene group, a triphenylene group, a pyrene group, a chrysene group, a naphthacene group, a picene group, a perylene group, a pentaphene group, an indenoanthracene group, a dibenzofuran group, a dibenzothiophene group, an imidazole group, a pyrazole group, a thiazole group, an isothiazole group, an oxazole group, an isoxazole group, a pyridine group, a pyrazine group, a pyridazine group, a pyrimidine group, an indazole group, a purine group, a quinoline group, an isoquinoline group, a benzoquinoline group, a phthalazine group, a naphthyridine group, a quinoxaline group, a quinazoline group, a cinnoline group, a phenanthridine group, an acridine group, a phenanthroline group, a phenazine group, a benzimidazole group, an isobenzothiazole group, a benzoxazole group, an isobenzoxazole group, a triazole group, a tetrazole group, an oxadiazole group, a triazine group, a thiadiazole group, an imidazopyridine group, an imidazopyrimidine group, or an azacarbazole group, each unsubstituted or substituted with at least one of deuterium, —F, —Cl, —Br, —I, a hydroxyl group, a cyano group, a nitro group, an amidino group, a hydrazine group, a hydrazone group, a C1-C20 alkyl group, a C1-C20 alkoxy group, a phenyl group, a biphenyl group, a terphenyl group, a naphthyl group, a cyano-containing phenyl group, a cyano-containing biphenyl group, a cyano-containing terphenyl group, a cyano-containing naphthyl group, a pyridinyl group, a phenylpyridinyl group, a diphenylpyridinyl group, a biphenylpyridinyl group, a di(biphenyl)pyridinyl group, a pyrazinyl group, a phenylpyrazinyl group, a diphenylpyrazinyl group, a biphenylpyrazinyl group, a di(biphenyl)pyrazinyl group, a pyridazinyl group, a phenylpyridazinyl group, a diphenylpyridazinyl group, a biphenylpyridazinyl group, a di(biphenyl)pyridazinyl group, a pyrimidinyl group, a phenylpyrimidinyl group, a diphenylpyrimidinyl group, a biphenylpyrimidinyl group, a di(biphenyl)pyrimidinyl group, a triazinyl group, a phenyltriazinyl group, a diphenyltriazinyl group, a biphenyltriazinyl group, a di(biphenyl)triazinyl group, —Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂).

at least one of L₃₀₁(s) in the number of xb1 may each independently be an imidazole group, a pyrazole group, a thiazole group, an isothiazole group, an oxazole group, an isoxazole group, a pyridine group, a pyrazine group, a pyridazine group, a pyrimidine group, an indazole group, a purine group, a quinoline group, an isoquinoline group, a benzoquinoline group, a phthalazine group, a naphthyridine group, a quinoxaline group, a quinazoline group, a cinnoline group, a phenanthridine group, an acridine group, a phenanthroline group, a phenazine group, a benzimidazole group, an isobenzothiazole group, a benzoxazole group, an isobenzoxazole group, a triazole group, a tetrazole group, an oxadiazole group, a triazine group, a thiadiazole group, an imidazopyridine group, an imidazopyrimidine group, or an azacarbazole group, each unsubstituted or substituted with at least one of deuterium. —F, —Cl, —Br, —I, a hydroxyl group, a cyano group, a nitro group, an amidino group, a hydrazine group, a hydrazone group, a C₁-C₂₀ alkyl group, a C₁-C₂₀ alkoxy group, a phenyl group, a biphenyl group, a terphenyl group, a naphthyl group, a cyano group-containing phenyl group, a cyano group-containing biphenyl group, a cyano group-containing terphenyl group, a cyano group-containing naphthyl group, a pyridinyl group, a phenylpyridinyl group, a diphenylpyridinyl group, a biphenylpyrdinyl group, a di(biphenyl)pyridinyl group, a pyrazinyl group, a phenylpyrazinyl group, a diphenylpyrazinyl group, a biphenylpyrazinyl group, a di(biphenyl)pyrazinyl group, a pyridazinyl group, a phenylpyridazinyl group, a diphenylpyrdazinyl group, a biphenylpyridazinyl group, a di(biphenyl)pyridazinyl group, a pyrimidinyl group, a phenylpyrimidinyl group, a diphenylpyrimidinyl group, a biphenylpyrimidinyl group, a di(biphenyl)pyrimidinyl group, a triazinyl group, a phenyltriazinyl group, a diphenyltriazinyl group, a biphenyltriazinyl group, a di(biphenyl)triazinyl group, —Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and

R₃₀₁ may be hydrogen, deuterium, —F, —Cl, —Br, —I, a hydroxyl group, a cyano group, a nitro group, an amidino group, a hydrazine group, a hydrazone group, a C1-C20 alkyl group, a C1-C20 alkoxy group, a phenyl group, a biphenyl group, a terphenyl group, a quaterphenyl group, a naphthyl group, a cyano-containing phenyl group, a cyano-containing biphenyl group, a cyano-containing terphenyl group, a cyano-containing quaterphenyl group, a cyano-containing naphthyl group, a pyridinyl group, a phenylpyridinyl group, a diphenylpyridinyl group, a biphenylpyridinyl group, a di(biphenyl)pyridinyl group, a pyrazinyl group, a phenylpyrazinyl group, a diphenylpyrazinyl group, a biphenylpyrazinyl group, a di(biphenyl)pyrazinyl group, a pyridazinyl group, a phenylpyridazinyl group, a diphenylpyridazinyl group, a biphenylpyridazinyl group, a di(biphenyl)pyridazinyl group, a pyrimidinyl group, a phenylpyrimidinyl group, a diphenylpyrimidinyl group, a biphenylpyrimidinyl group, a di(biphenyl)pyrimidinyl group, a triazinyl group, a phenyltriazinyl group, a diphenyltriazinyl group, a biphenyltriazinyl group, a di(biphenyl)triazinyl group, —Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂),

wherein Q₃₁ to Q₃₃ may each independently be a C₁-C₁₀ alkyl group, a C₁-C₁₀ alkoxy group, a phenyl group, a biphenyl group, a terphenyl group, or a naphthyl group, but are not limited thereto.

In one or more embodiments,

Ar₃₀₁ may be a benzene group, a naphthalene group, a fluorene group, a spiro-bifluorene group, a benzofluorene group, a dibenzofluorene group, a phenalene group, a phenanthrene group, an anthracene group, a fluoranthene group, a triphenylene group, a pyrene group, a chrysene group, a naphthacene group, a picene group, a perylene group, a pentaphene group, an indenoanthracene group, a dibenzofuran group, or a dibenzothiophene group, each unsubstituted or substituted with at least one of deuterium, —F, —Cl, —Br, —I, a hydroxyl group, a cyano group, a nitro group, an amidino group, a hydrazine group, a hydrazone group, a C₁-C₂₀ alkyl group, a C₁-C₂₀ alkoxy group, a phenyl group, a biphenyl group, a terphenyl group, a naphthyl group, a cyano-containing phenyl group, a cyano-containing biphenyl group, a cyano-containing terphenyl group, a cyano-containing naphthyl group, a pyrdinyl group, a phenylpyridinyl group, a diphenylpyridinyl group, a biphenylpyrdinyl group, a di(biphenyl)pyndinyl group, a pyrazinyl group, a phenylpyrazinyl group, a diphenylpyrazinyl group, a biphenylpyrazinyl group, a di(biphenyl)pyrazinyl group, a pyridazinyl group, a phenylpyridazinyl group, a diphenylpyridazinyl group, a biphenylpyridazinyl group, a di(biphenyl)pyridazinyl group, a pyrmidinyl group, a phenylpyrimidinyl group, a diphenylpyrmidinyl group, a biphenylpyrmidinyl group, a di(biphenyl)pyrmidinyl group, a triazinyl group, a phenyltriazinyl group, a diphenyltriazinyl group, a biphenyltriazinyl group, a di(biphenyl)triazinyl group, —Si(Q₃₁)(Q₃₂)(Q₃₃), —N(Q₃₁)(Q₃₂), —B(Q₃₁)(Q₃₂). —C(═O)(Q₃₁), —S(═O)₂(Q₃₁), or —P(═O)(Q₃₁)(Q₃₂); and

L₃₀₁ may be a group represented by one of Formulae 5-1 to 5-3 or Formulae 6-1 to 6-33:

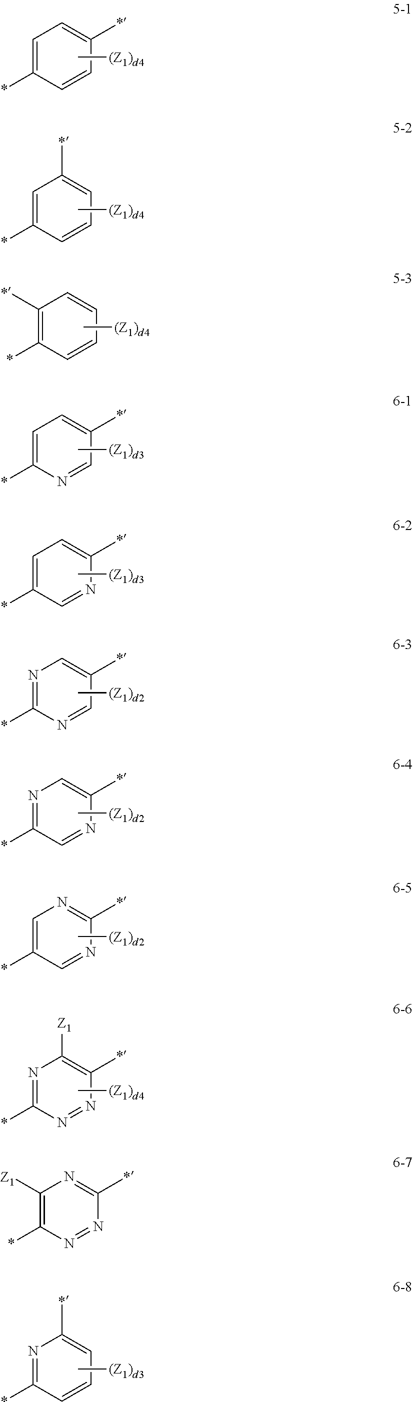

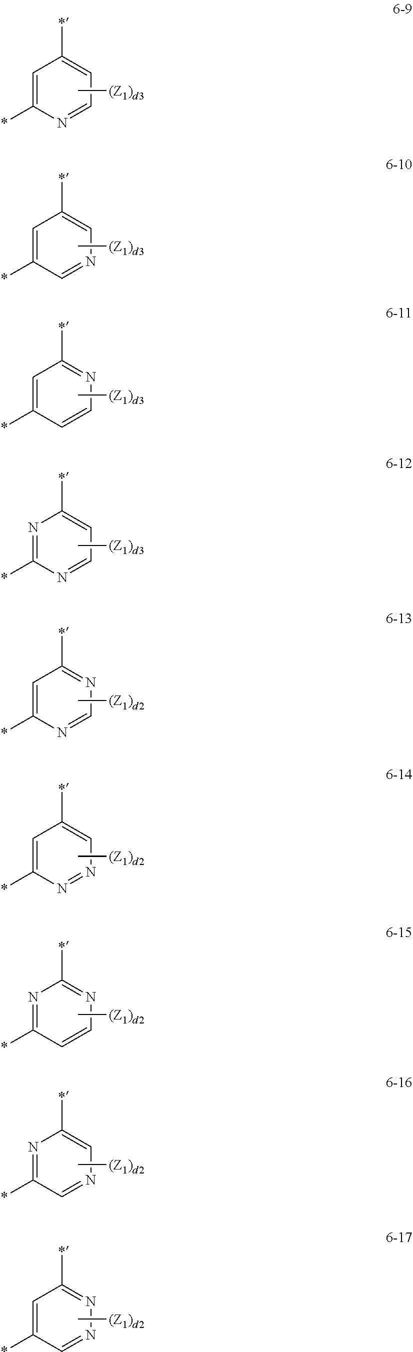

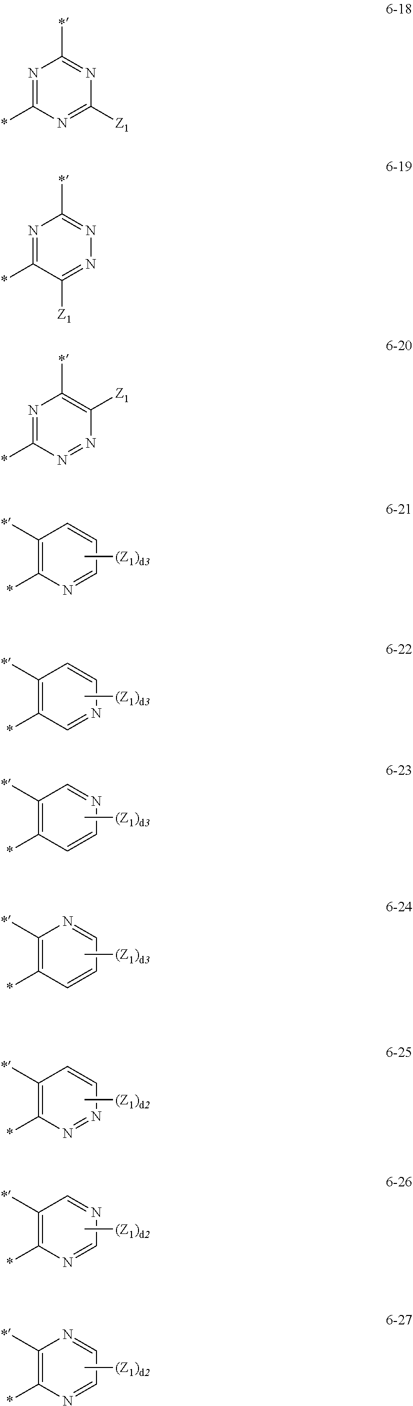

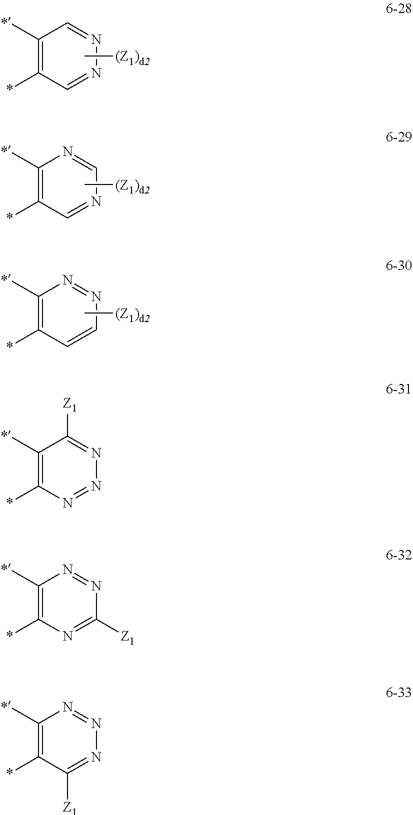

wherein, in Formulae 5-1 to 5-3 and 6-1 to 6-33.

Z₁ may be hydrogen, deuterium. —F, —Cl, —Br, —I, a hydroxyl group, a cyano group, a nitro group, an amidino group, a hydrazine group, a hydrazone group, a C1-C20 alkyl group, a C1-C20 alkoxy group, a phenyl group, a biphenyl group, a terphenyl group, a naphthyl group, a cyano-containing phenyl group, a cyano-containing biphenyl group, a cyano-containing terphenyl group, a cyano-containing naphthyl group, a pyridinyl group, a phenylpyridinyl group, a diphenylpyridinyl group, a biphenylpyridinyl group, a di(biphenyl)pyridinyl group, a pyrazinyl group, a phenylpyrazinyl group, a diphenylpyrazinyl group, a biphenylpyrazinyl group, a di(biphenyl)pyrazinyl group, a pyridazinyl group, a phenylpyridazinyl group, a diphenylpyridazinyl group, a biphenylpyridazinyl group, a di(biphenyl)pyridazinyl group, a pyrimidinyl group, a phenylpyrimidinyl group, a diphenylpyrimidinyl group, a biphenylpyrimidinyl group, a di(biphenyl)pyrimidinyl group, a triazinyl group, a phenyltriazinyl group, a diphenyltriazinyl group, a biphenyltriazinyl group, a di(biphenyl)triazinyl group, —Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂),

d4 may be 0, 1, 2, 3, or 4,

d3 may be 0, 1, 2, or 3,

d2 may be 0, 1, or 2,

* and *′ each indicate a binding site to a neighboring atom, and

Q₃₁ to Q₃₃ are the same as described above.

In one or more embodiments, L₃₀₁ may be a group represented by one of Formulae 5-2, 5-3 or 6-8 to 6-33.

In one or more embodiments, R₃₀₁ may be a cyano group or a group represented by one of Formula 7-1 to 7-18, and at least one of Ar₄₀₂(s) in the number of xd11 may be a group represented by one of Formulae 7-1 to 7-18, but embodiments of the present disclosure are not limited thereto:

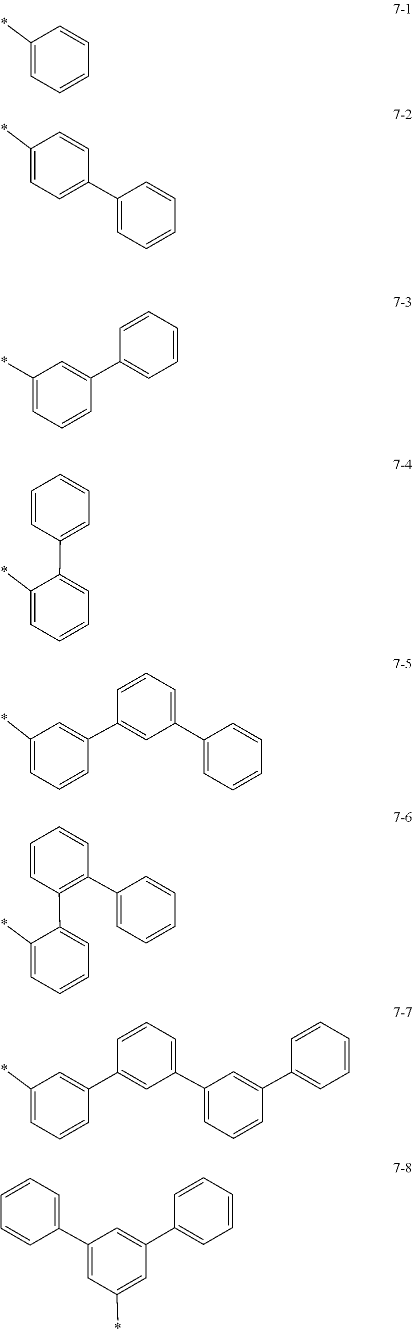

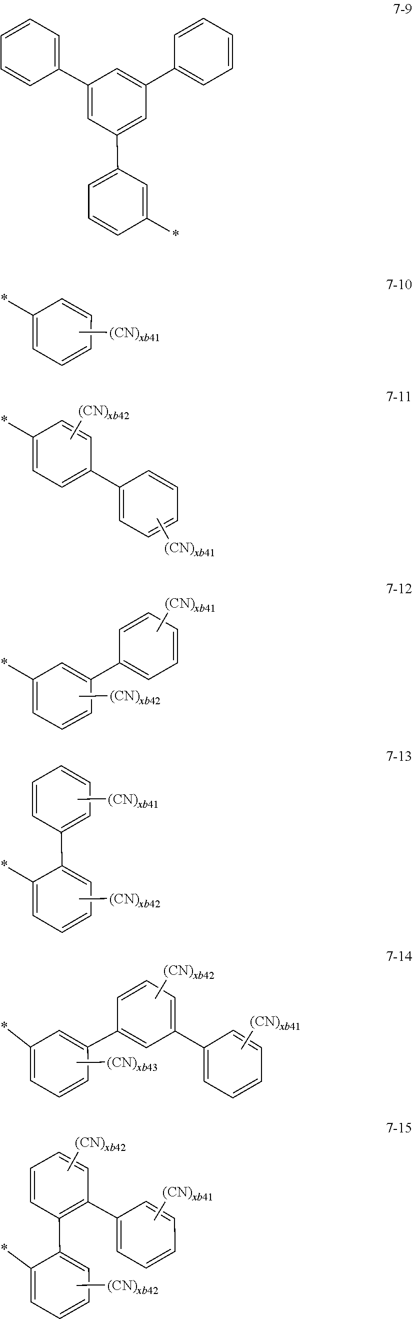

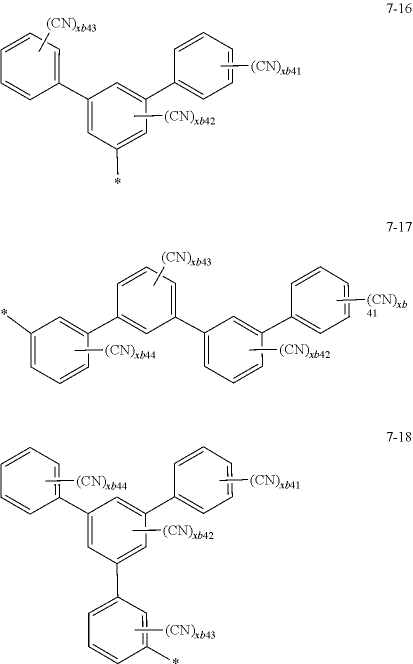

wherein, in Formulae 7-1 to 7-18,

xb41 to xb44 may each independently be 0, 1, or 2,

xb41 in Formula 7-10 may not be 0,

the sum of xb41 and xb42 in Formulae 7-11 to 7-13 may not be 0,

the sum of xb41, xb42, and xb43 in Formulae 7-14 to 7-16 may not be 0,

the sum of xb41, xb42, xb43, and xb44 in Formulae 7-17 and 7-18 may not be 0, and

* indicates a binding site to a neighboring atom.

In one or more embodiments, at least one of the following conditions is satisfied:

xb41 in Formula 7-10 is not 0,

the sum of xb41 and xb42 in Formulae 7-11 to 7-13 is not 0, the sum of xb41, xb42, and xb43 in Formulae 7-14 to 7-16 is not 0, or

the sum of xb41, xb42, xb43, and xb44 in Formulae 7-17 and 7-18 is not 0.

Two or more Ar₃₀₁(s) in Formula E-1 may be identical to or different from each other, two or more L₃₀₁(s) may be identical to or different from each other, two or more L₄₀₁(s) in Formula H-1 may be identical to or different from each other, and two or more Ar₄₀₂(s) in Formula H-1 may be identical to or different from each other.

In one or more embodiments, the electron transport host includes i) at least one of a cyano group, a pyrimidine group, a pyrazine group, and a triazine group and ii) a triphenylene group, and the hole transport host may include a carbazole group.

In one or more embodiments, the electron transport host may include at least one cyano group.

The electron transport host may be, for example, a compound of Group HE1 to HE7, but embodiments of the present disclosure are not limited thereto:

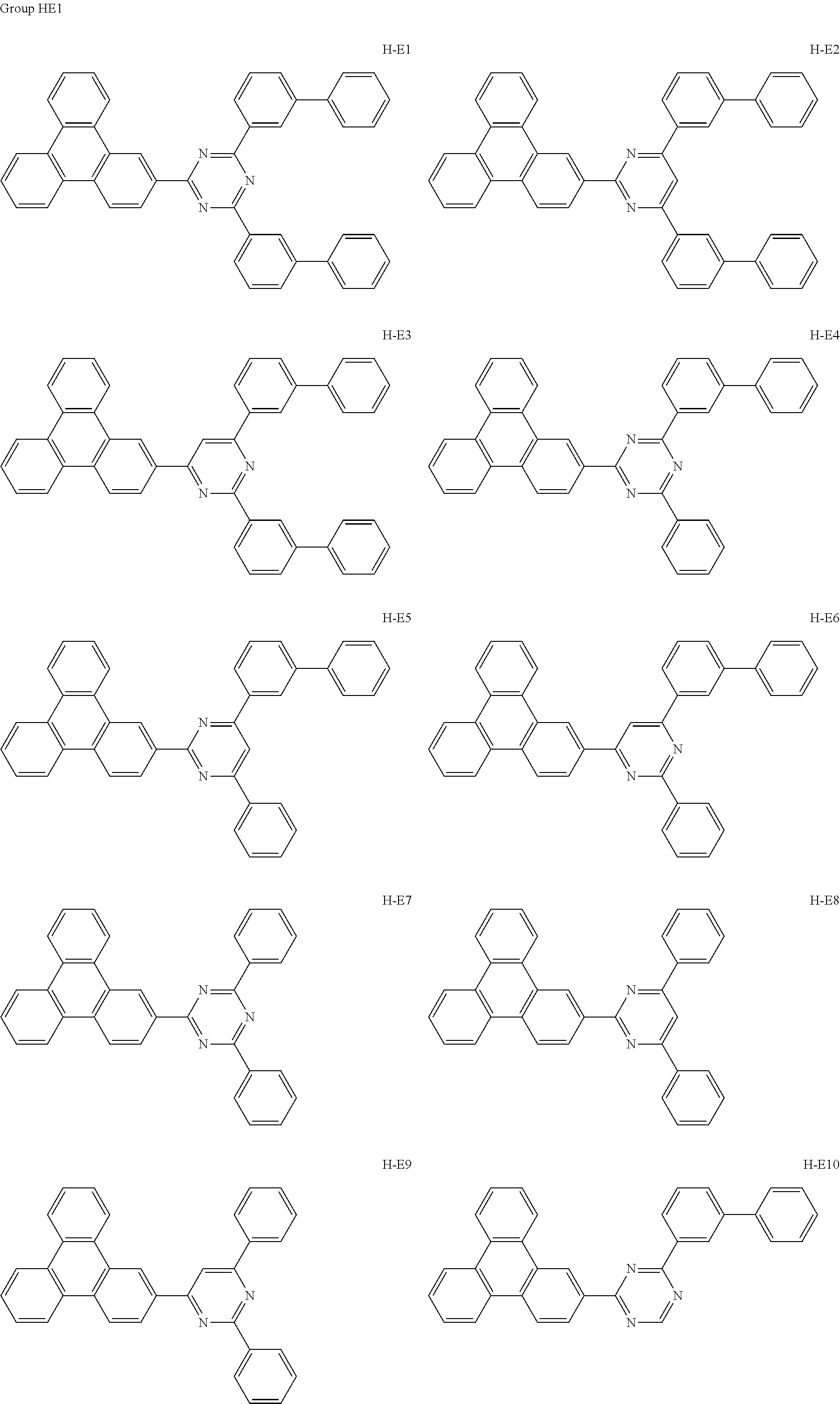

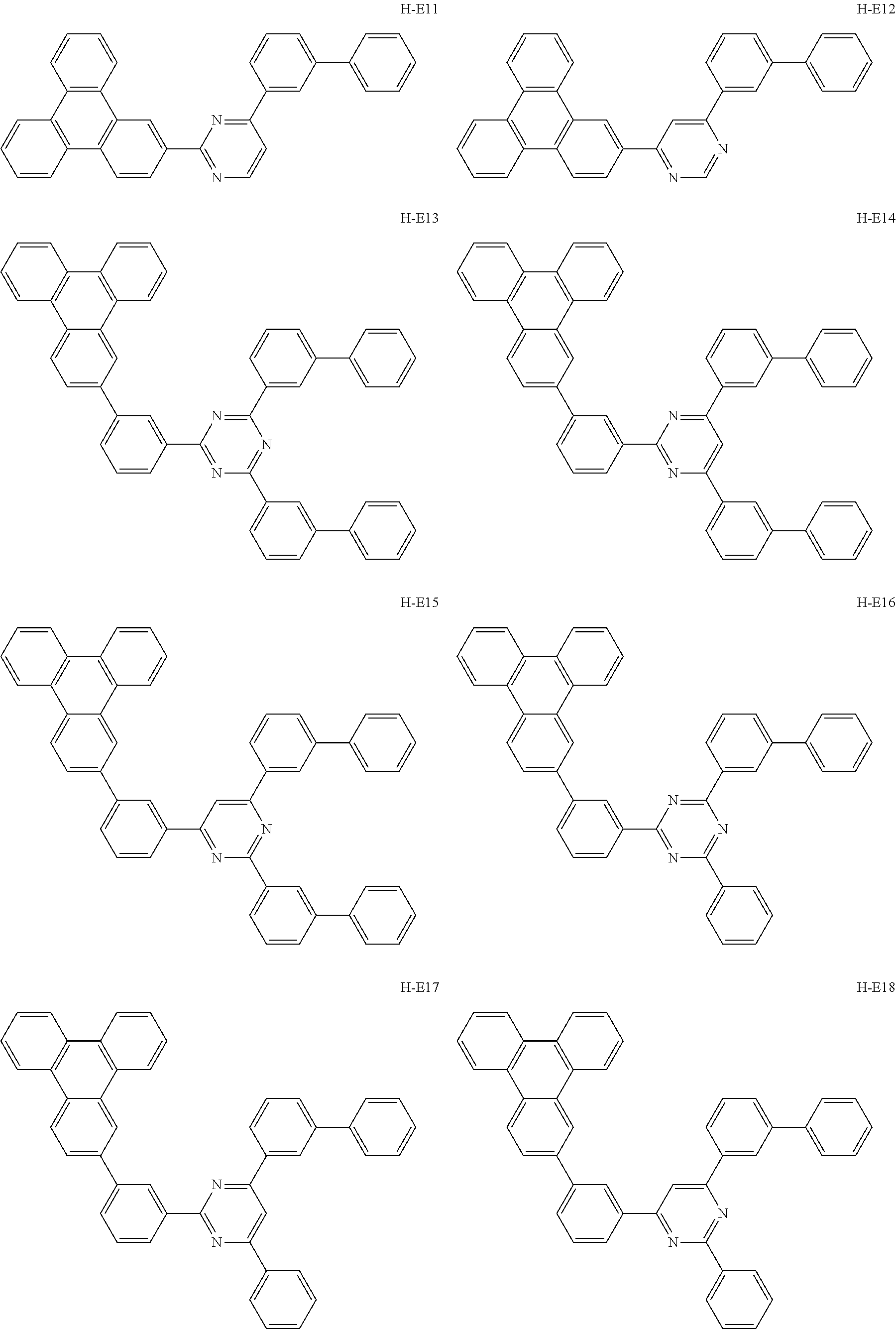

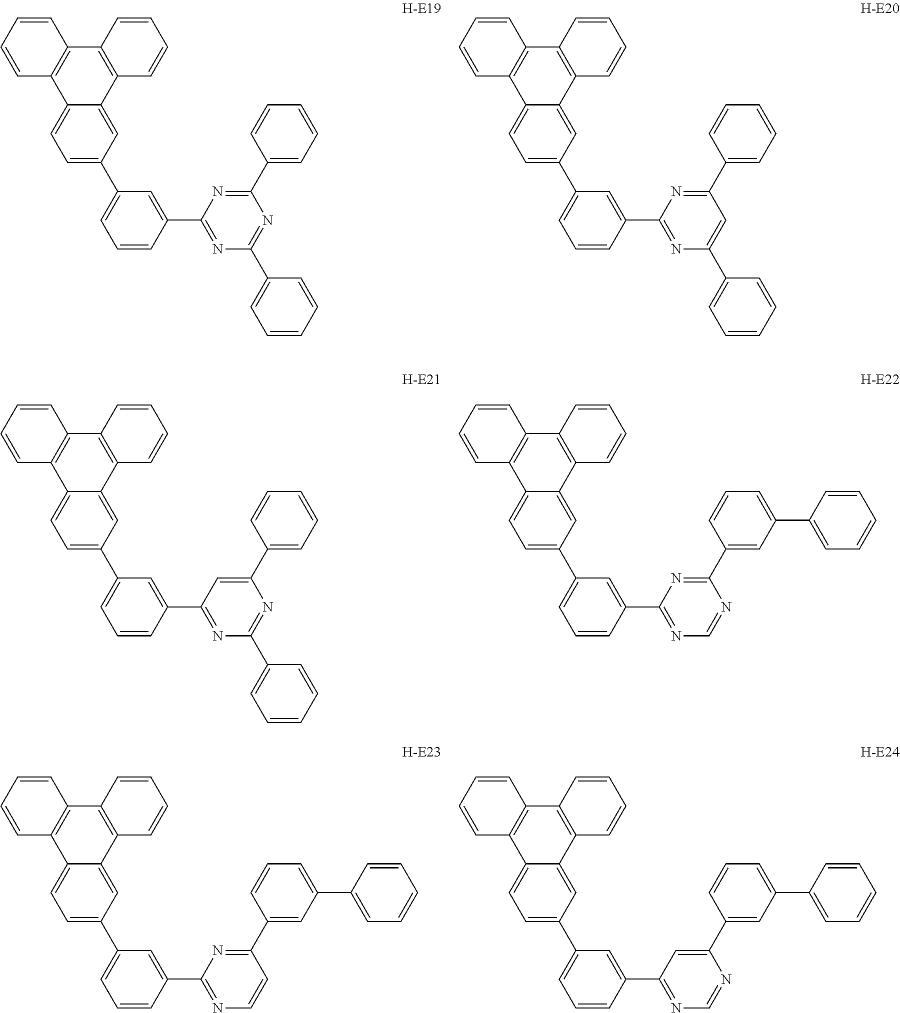 [SMILES: c1ccc(-c2nc(-c3ccccc3)nc(-c3cccc(-c4ccc5c6ccccc6c6ccccc6c5c4)c3)n2)cc1 ; c1ccc(-c2cc(-c3ccccc3)nc(-c3cccc(-c4ccc5c6ccccc6c6ccccc6c5c4)c3)n2)cc1 ; c1ccc(-c2cc(-c3cccc(-c4ccc5c6ccccc6c6ccccc6c5c4)c3)nc(-c3ccccc3)n2)cc1 ; c1ccc(-c2cccc(-c3ncnc(-c4cccc(-c5ccc6c7ccccc7c7ccccc7c6c5)c4)n3)c2)cc1 ; c1ccc(-c2cccc(-c3ccnc(-c4cccc(-c5ccc6c7ccccc7c7ccccc7c6c5)c4)n3)c2)cc1 ; c1ccc(-c2cccc(-c3cc(-c4cccc(-c5ccc6c7ccccc7c7ccccc7c6c5)c4)ncn3)c2)cc1]

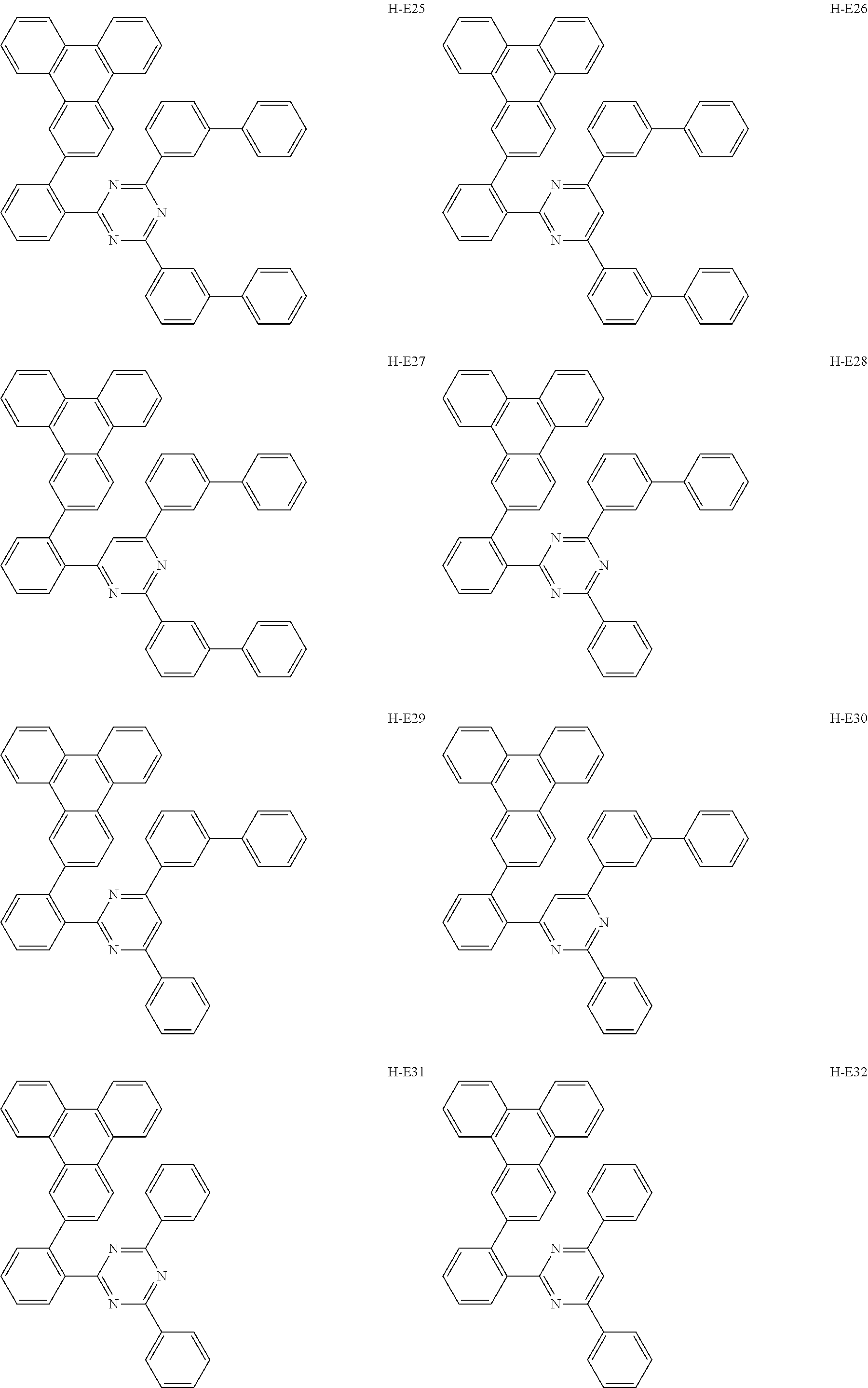

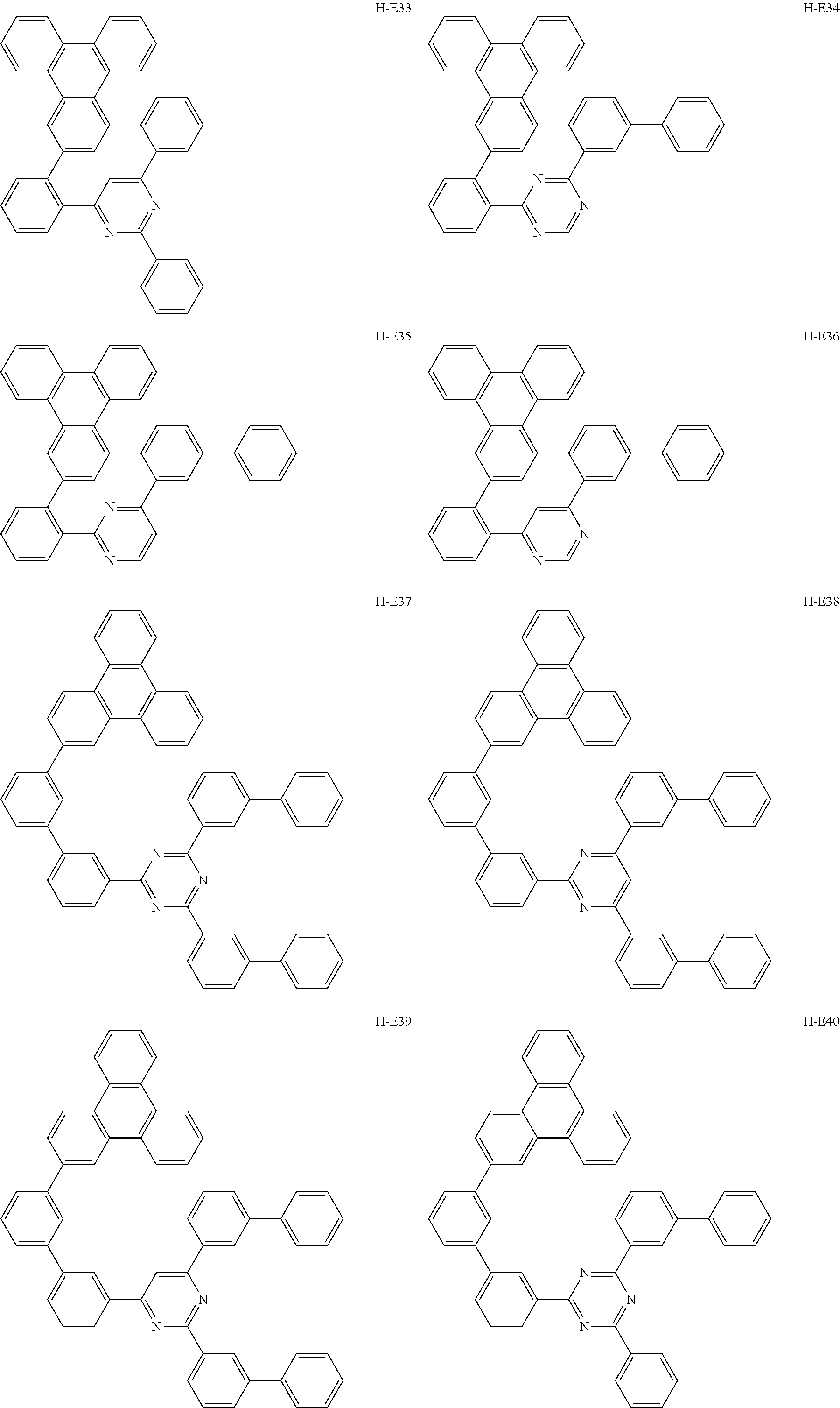

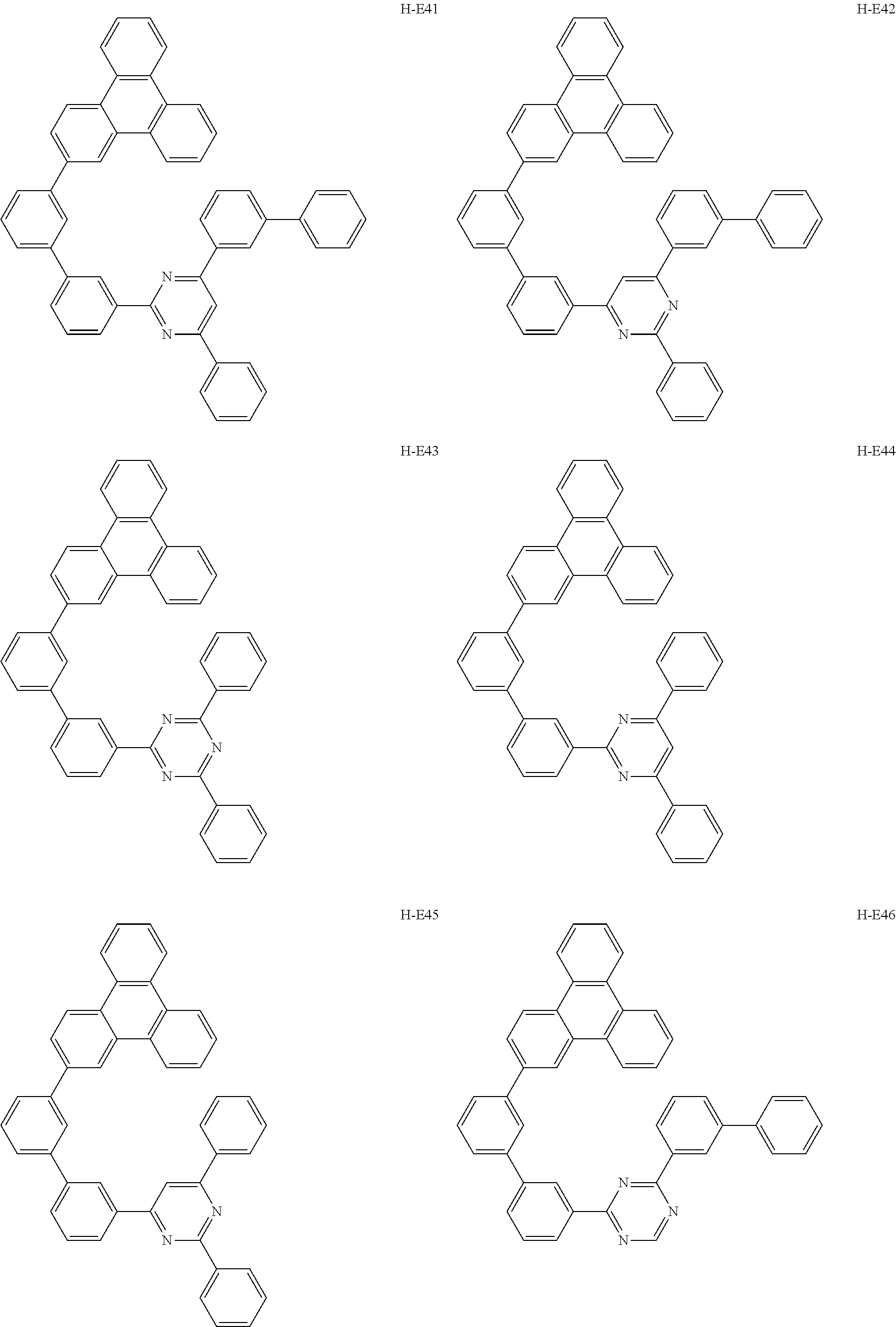

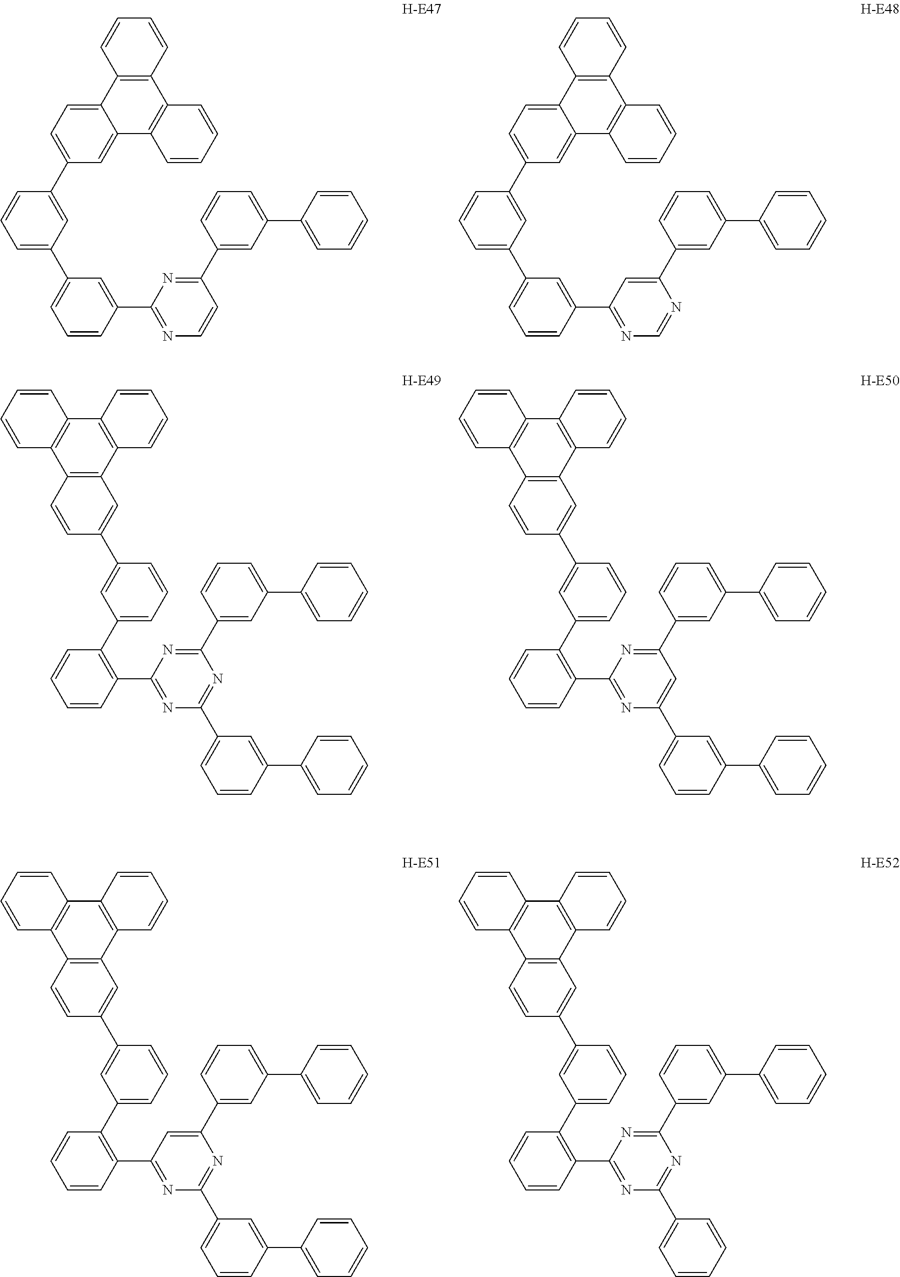

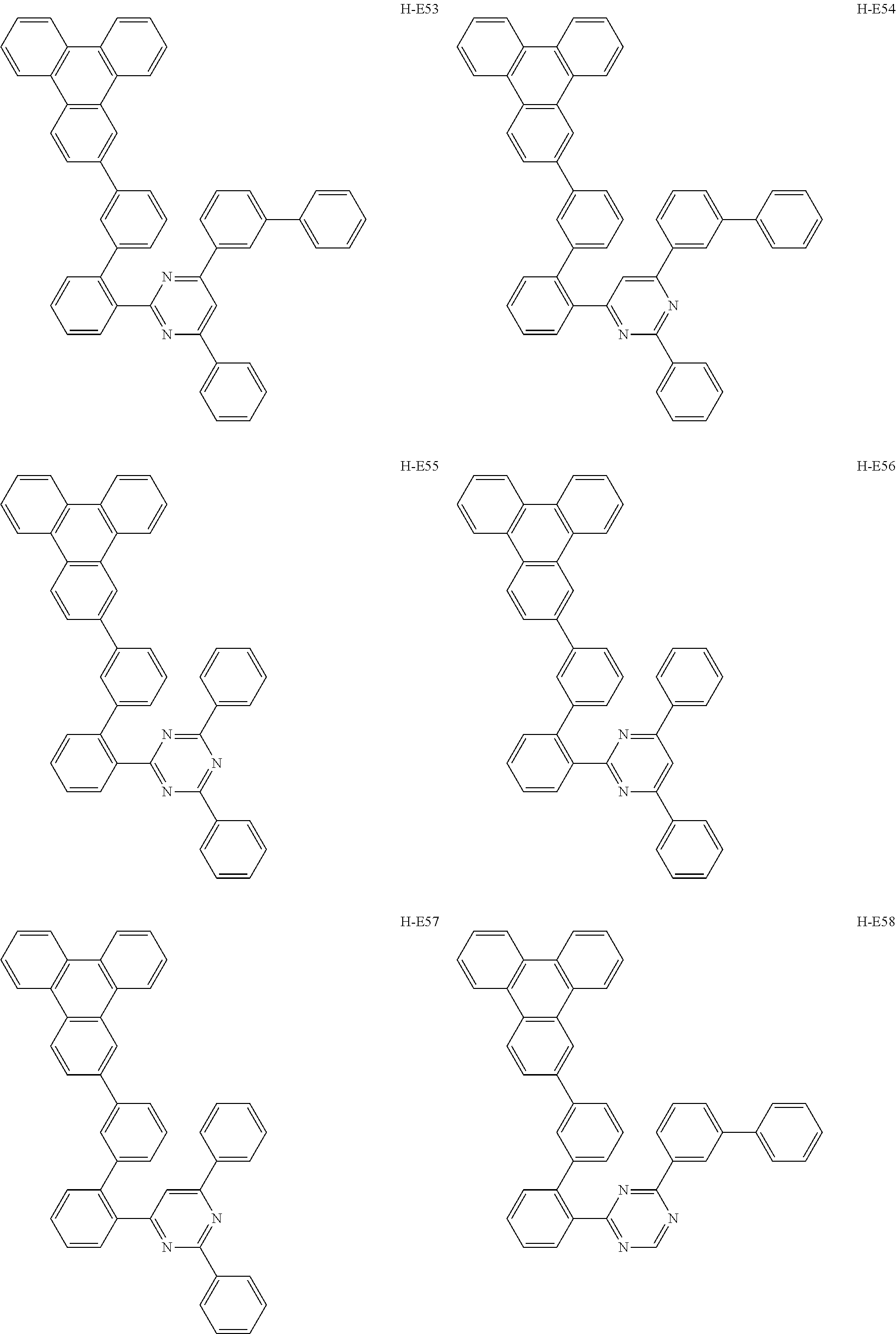

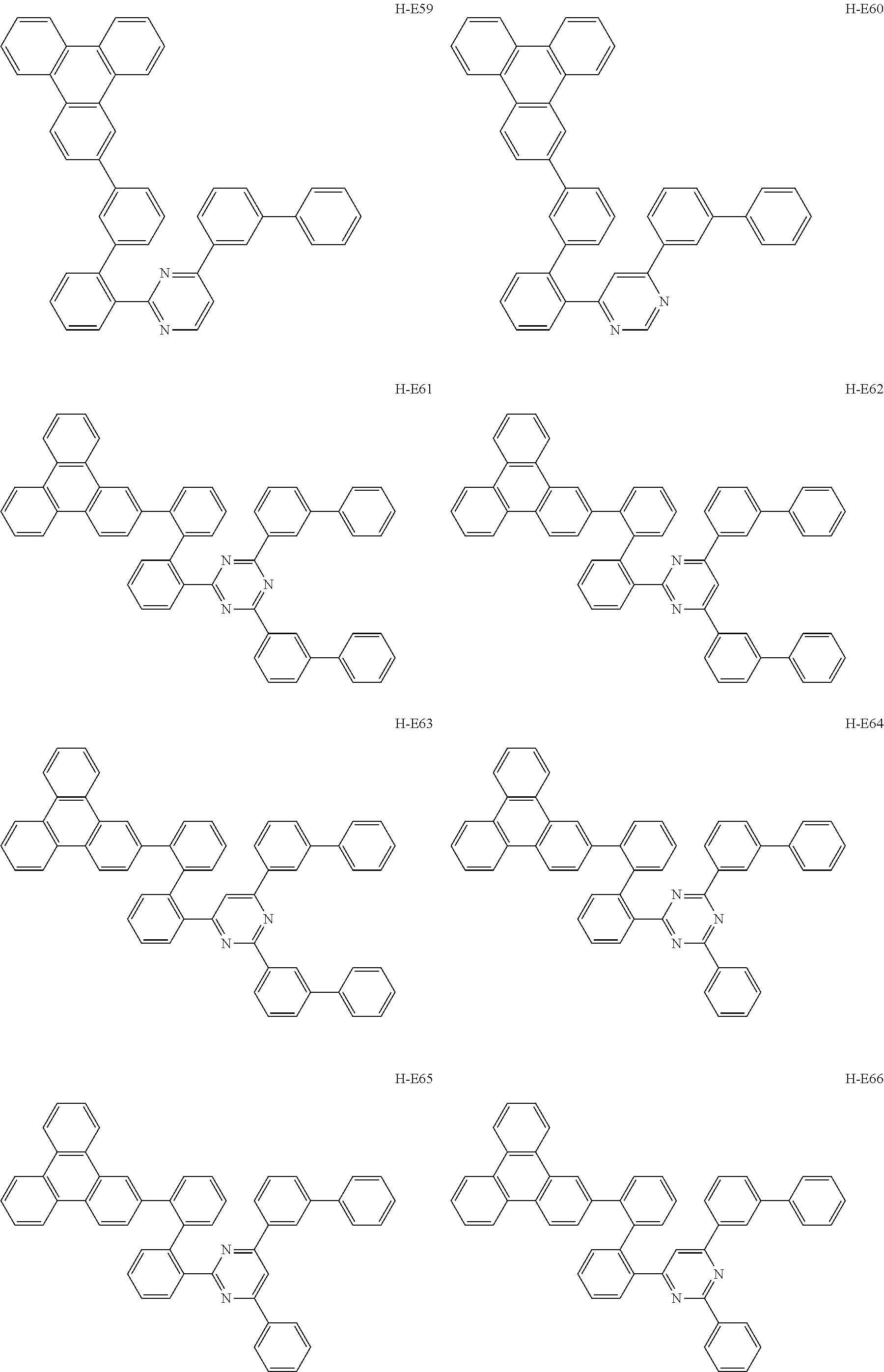

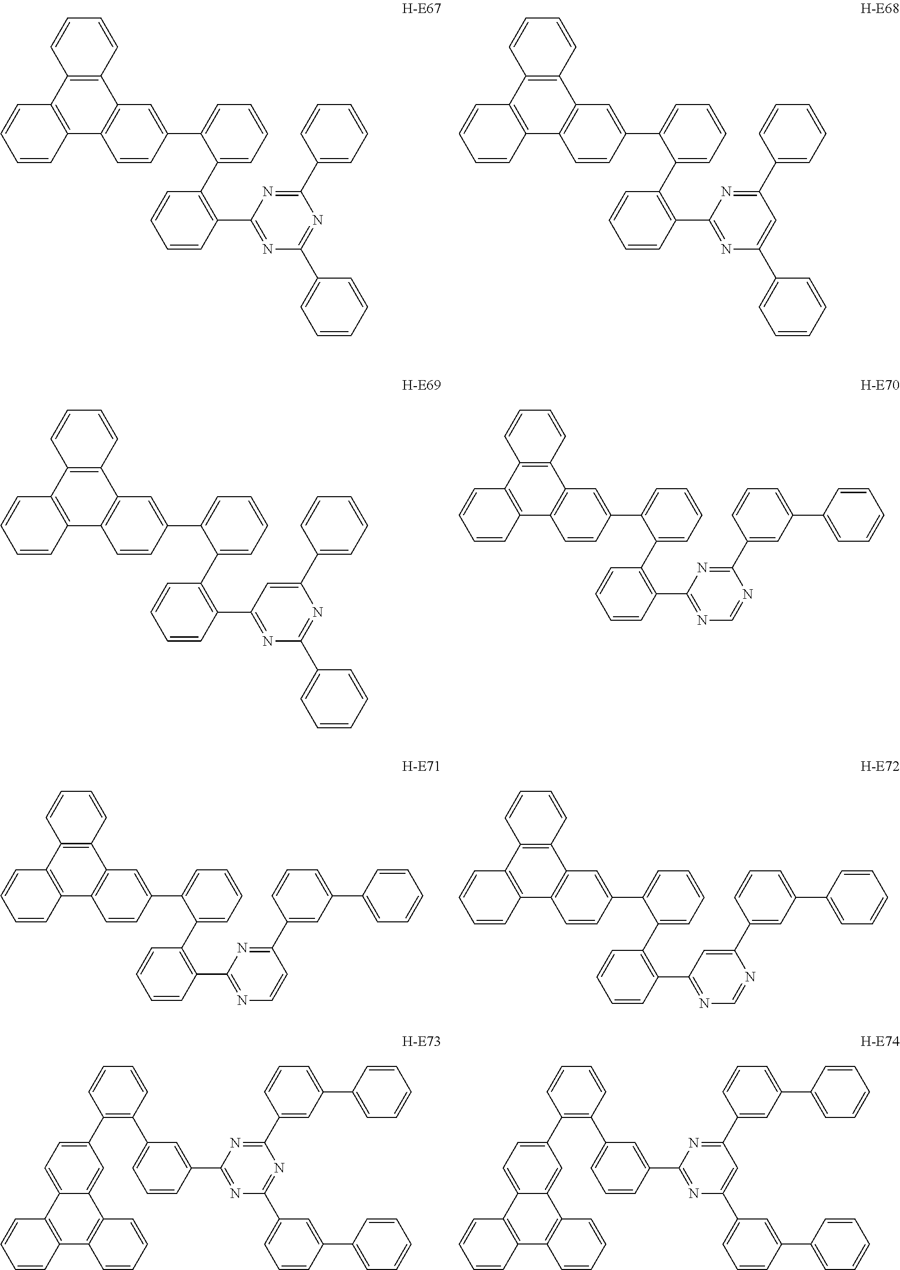

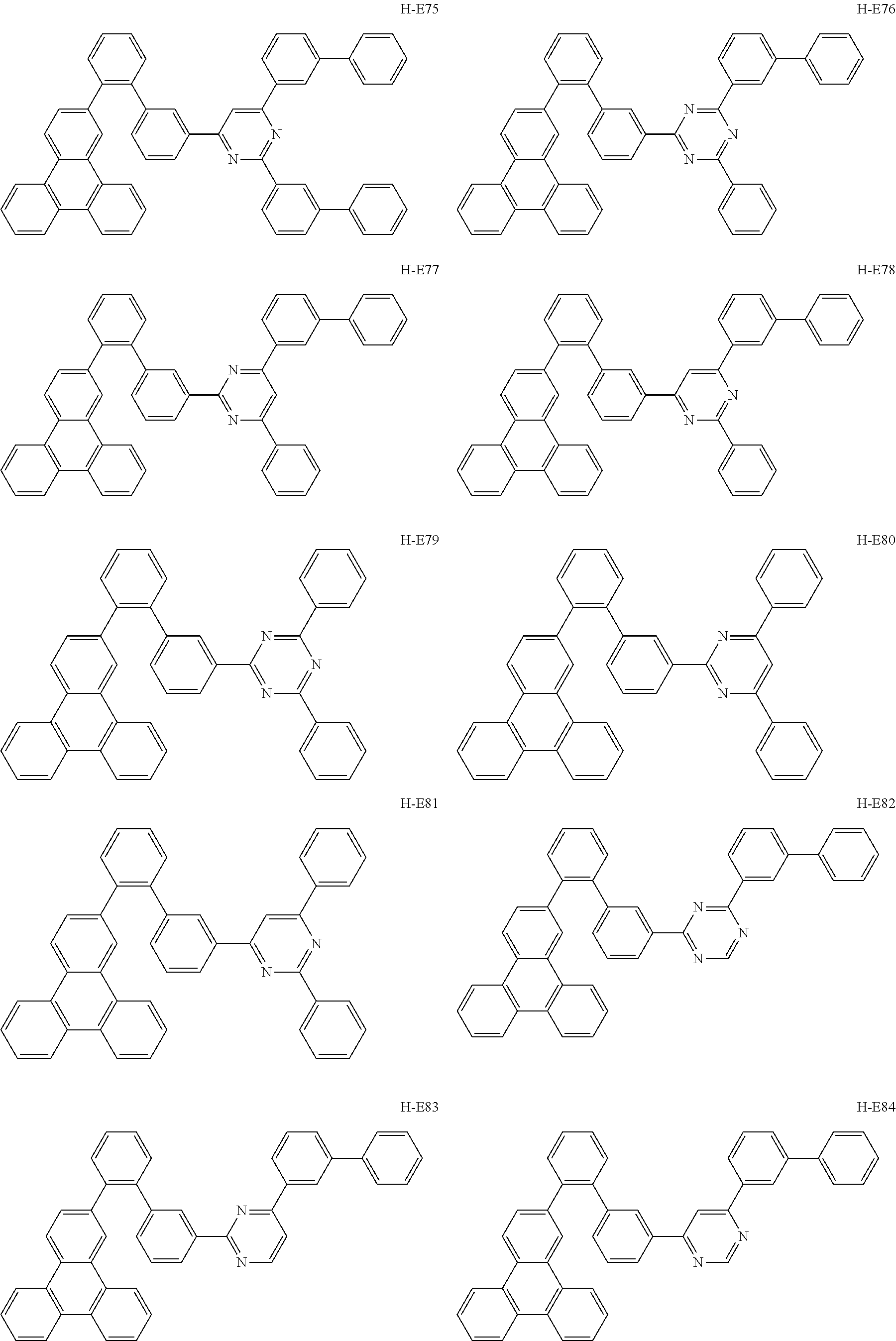

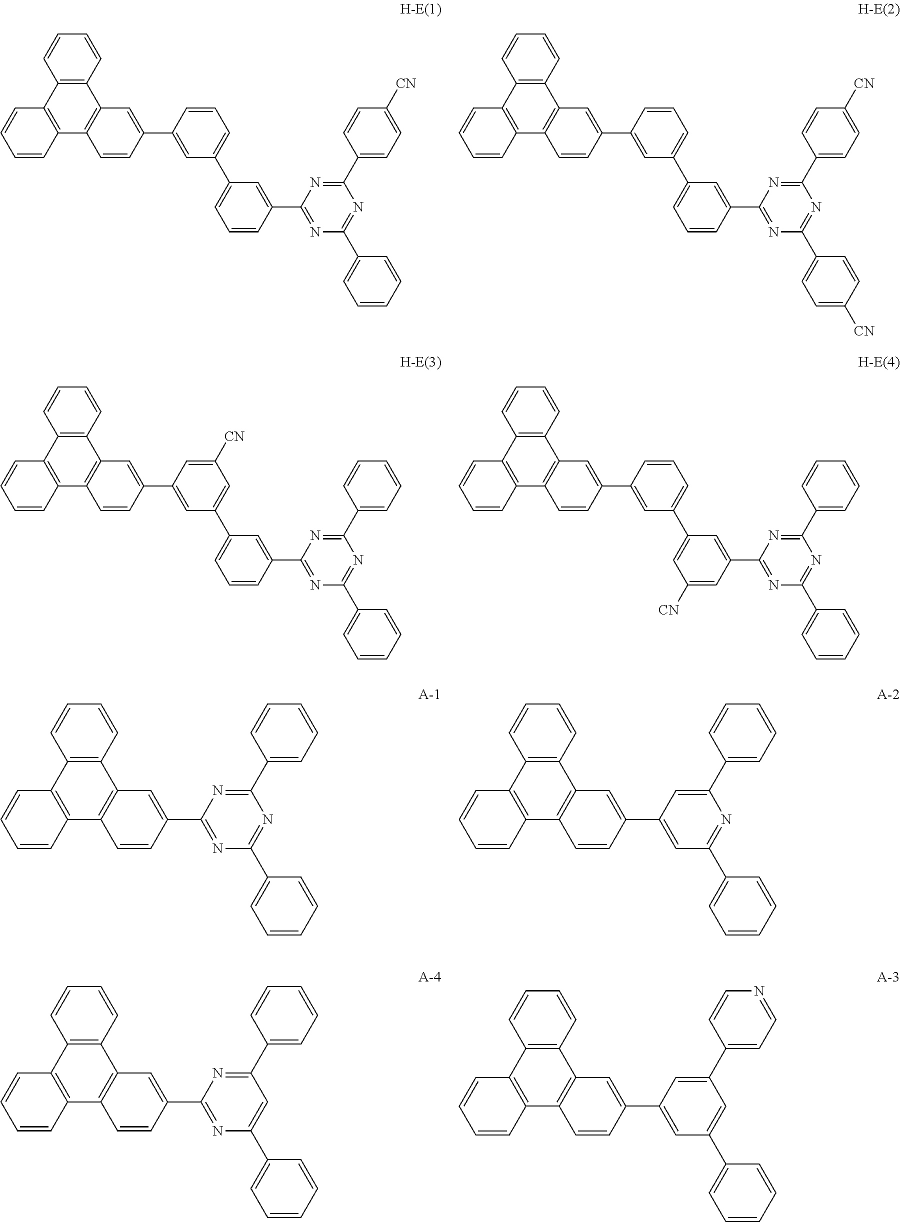

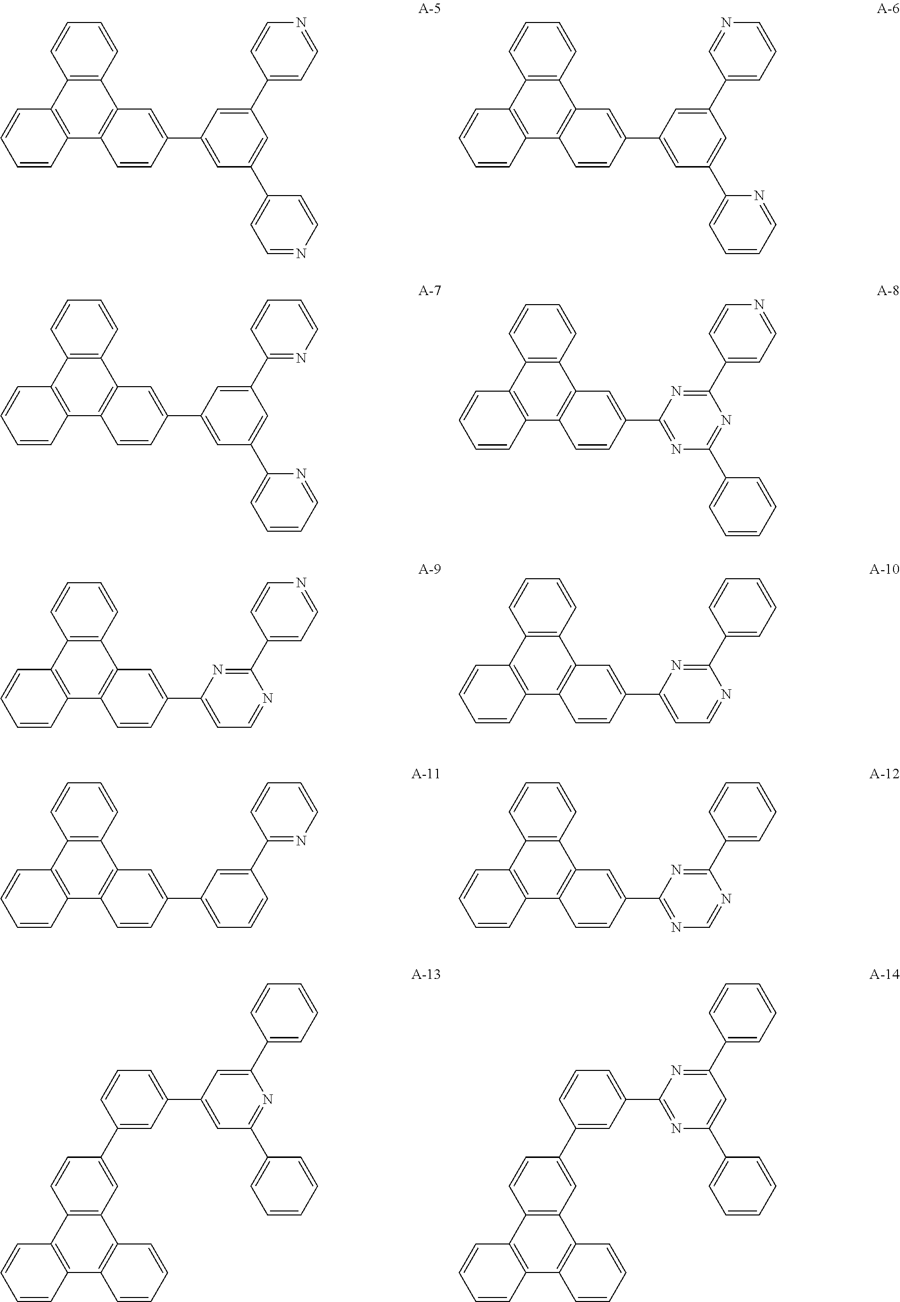

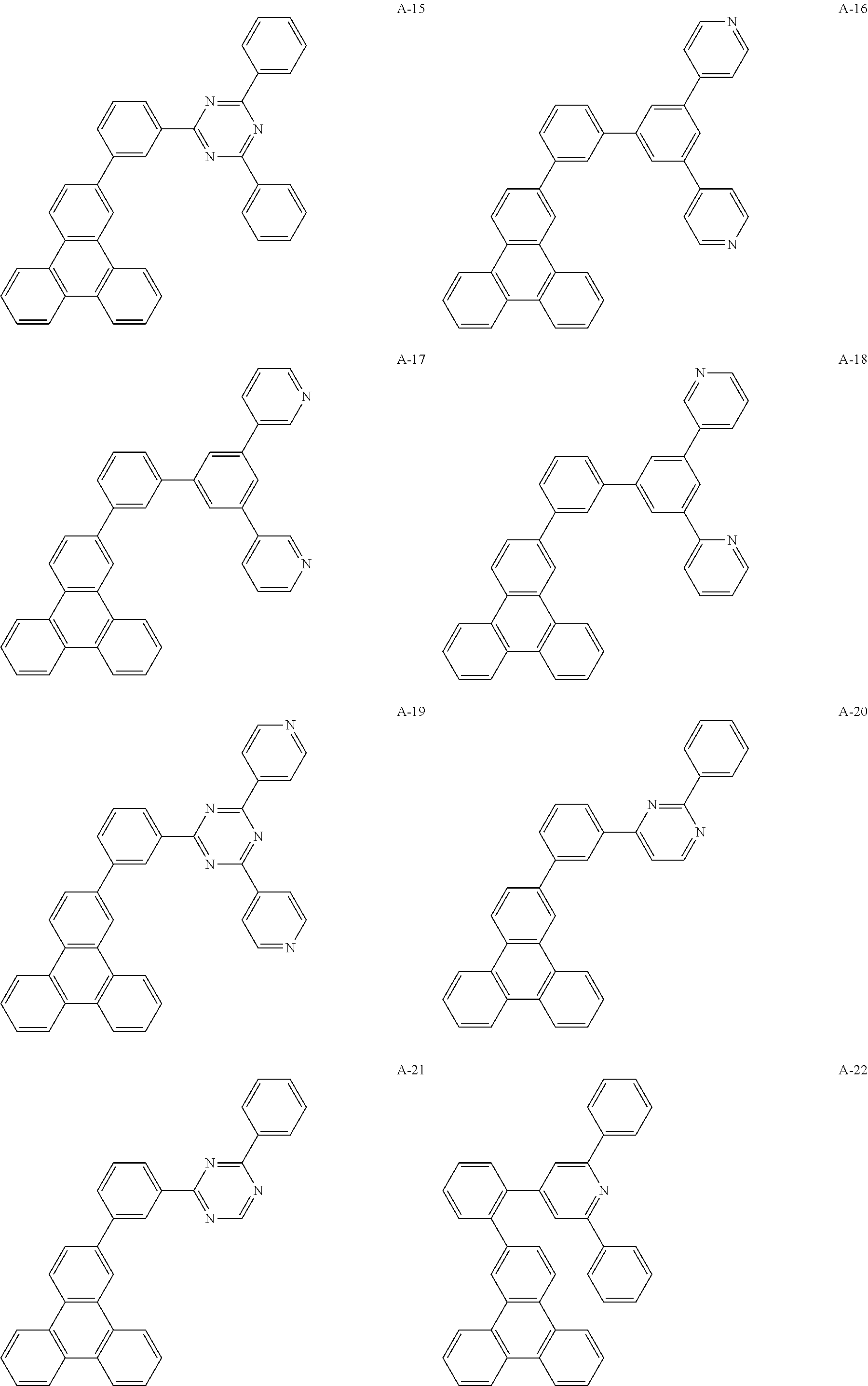

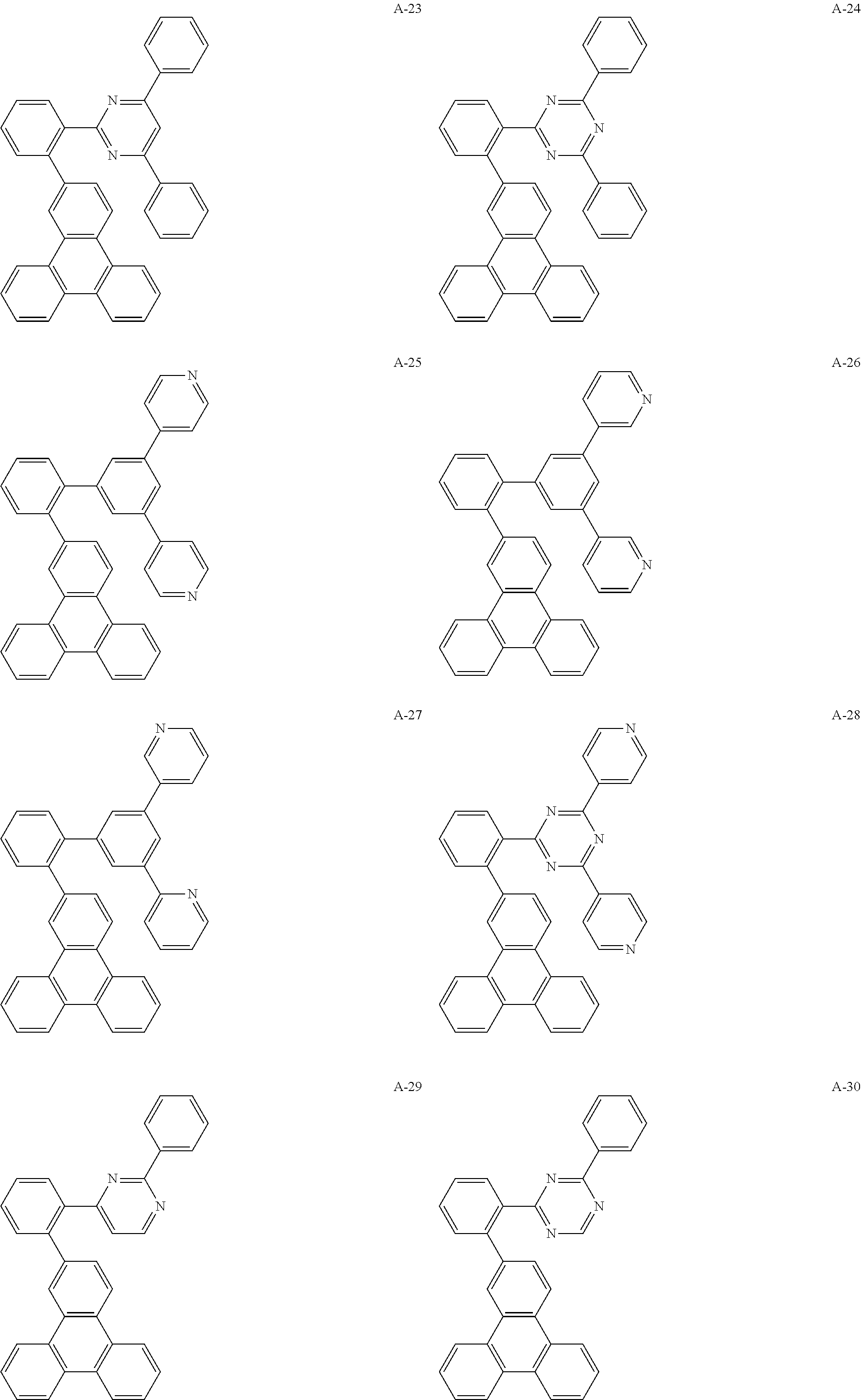

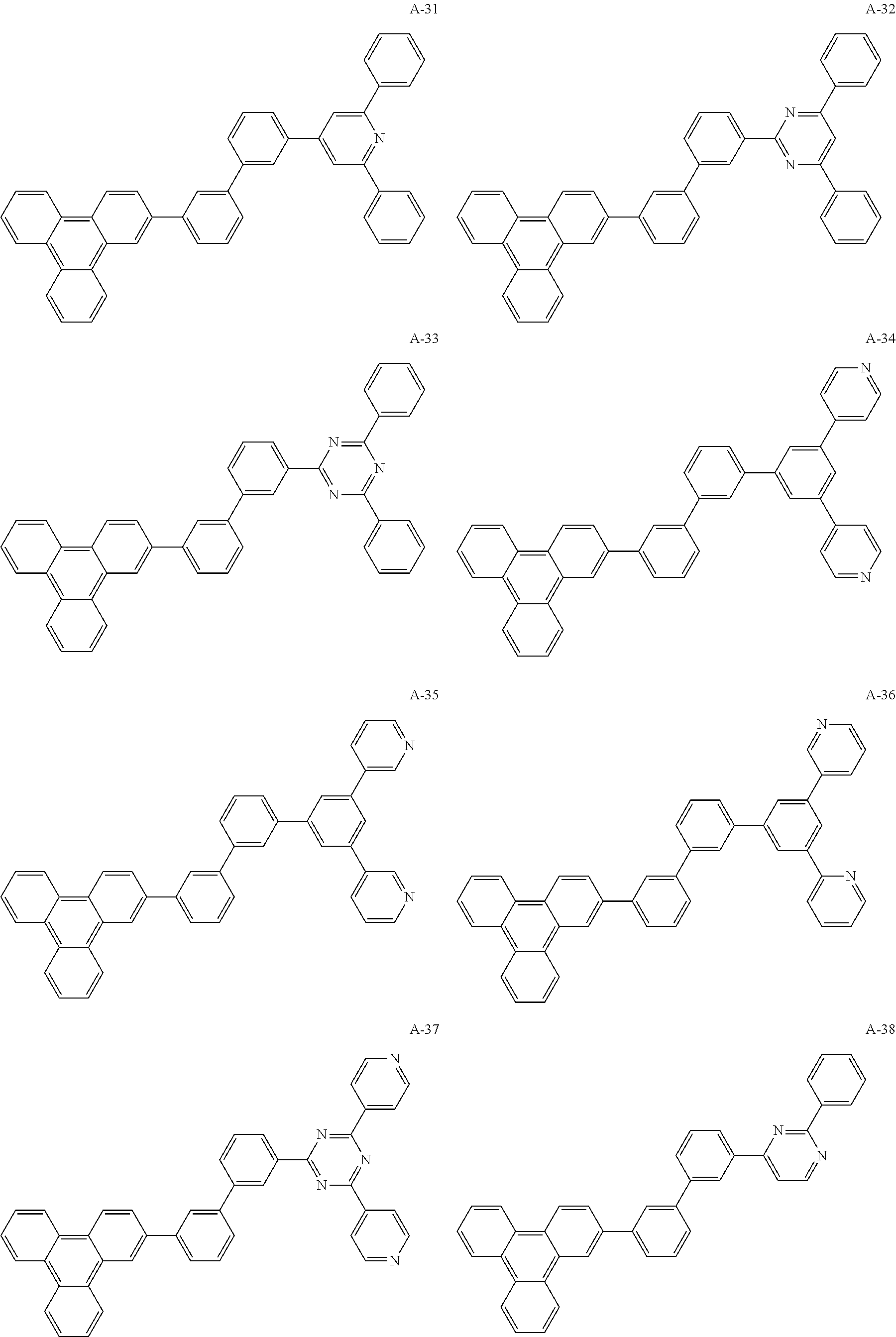

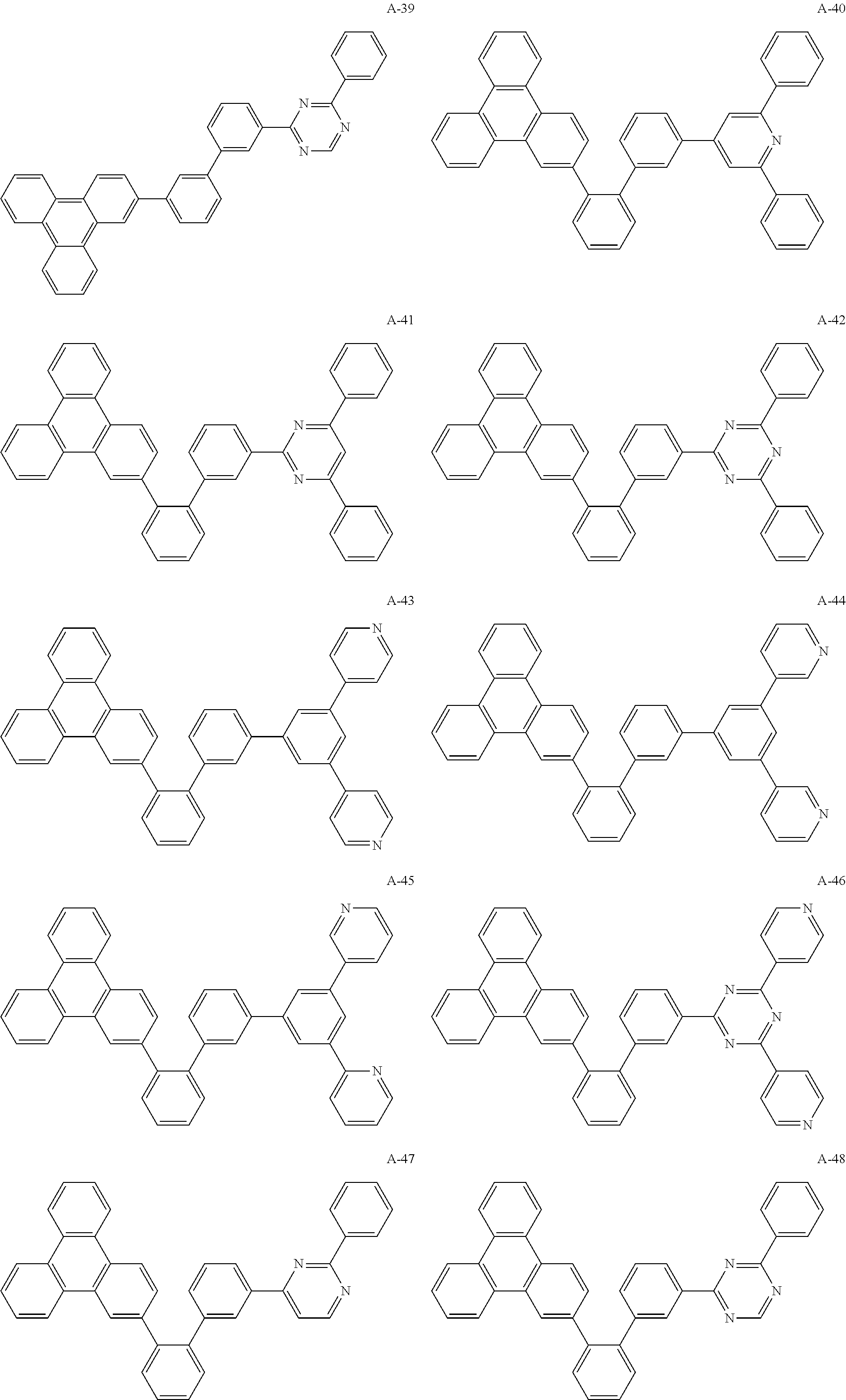

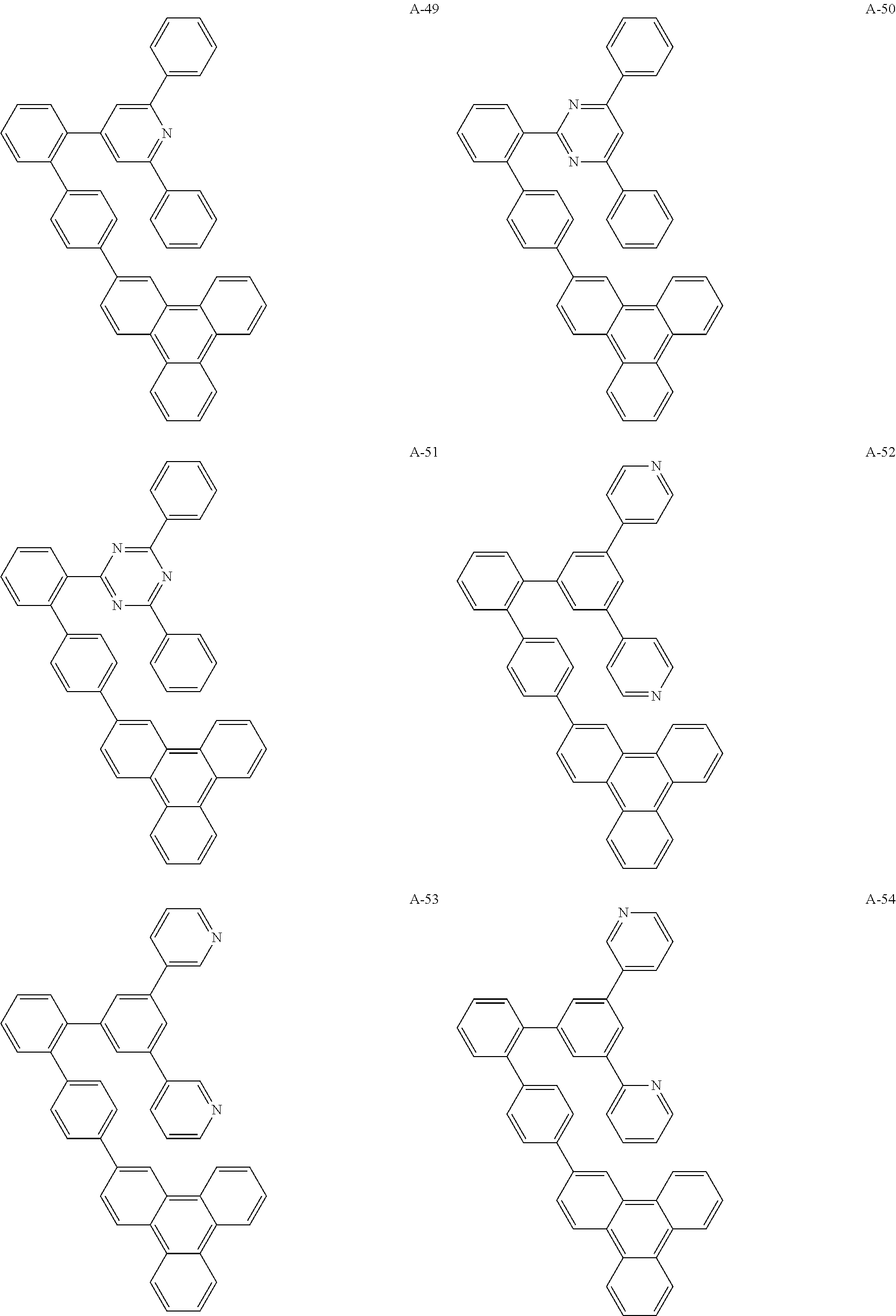

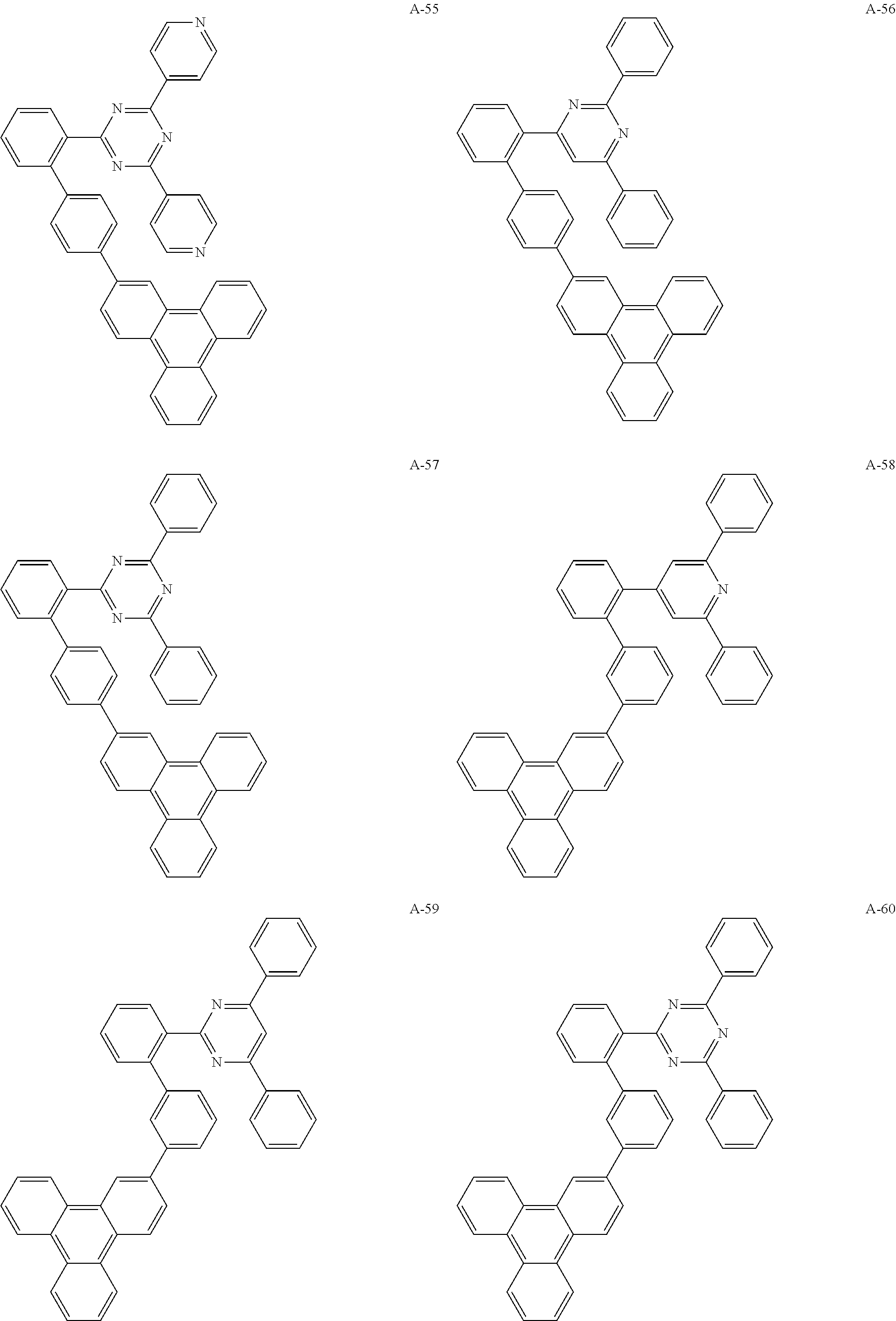 [SMILES: c1ccc(-c2nc(-c3ccncc3)nc(-c3ccncc3)n2)c(-c2ccc(-c3ccc4c5ccccc5c5ccccc5c4c3)cc2)c1 ; c1ccc(-c2cc(-c3ccccc3-c3ccc(-c4ccc5c6ccccc6c6ccccc6c5c4)cc3)nc(-c3ccccc3)n2)cc1 ; c1ccc(-c2nc(-c3ccccc3)nc(-c3ccccc3-c3ccc(-c4ccc5c6ccccc6c6ccccc6c5c4)cc3)n2)cc1 ; c1ccc(-c2cc(-c3ccccc3-c3cccc(-c4ccc5c6ccccc6c6ccccc6c5c4)c3)cc(-c3ccccc3)n2)cc1 ; c1ccc(-c2cc(-c3ccccc3)nc(-c3ccccc3-c3cccc(-c4ccc5c6ccccc6c6ccccc6c5c4)c3)n2)cc1 ; c1ccc(-c2nc(-c3ccccc3)nc(-c3ccccc3-c3cccc(-c4ccc5c6ccccc6c6ccccc6c5c4)c3)n2)cc1]

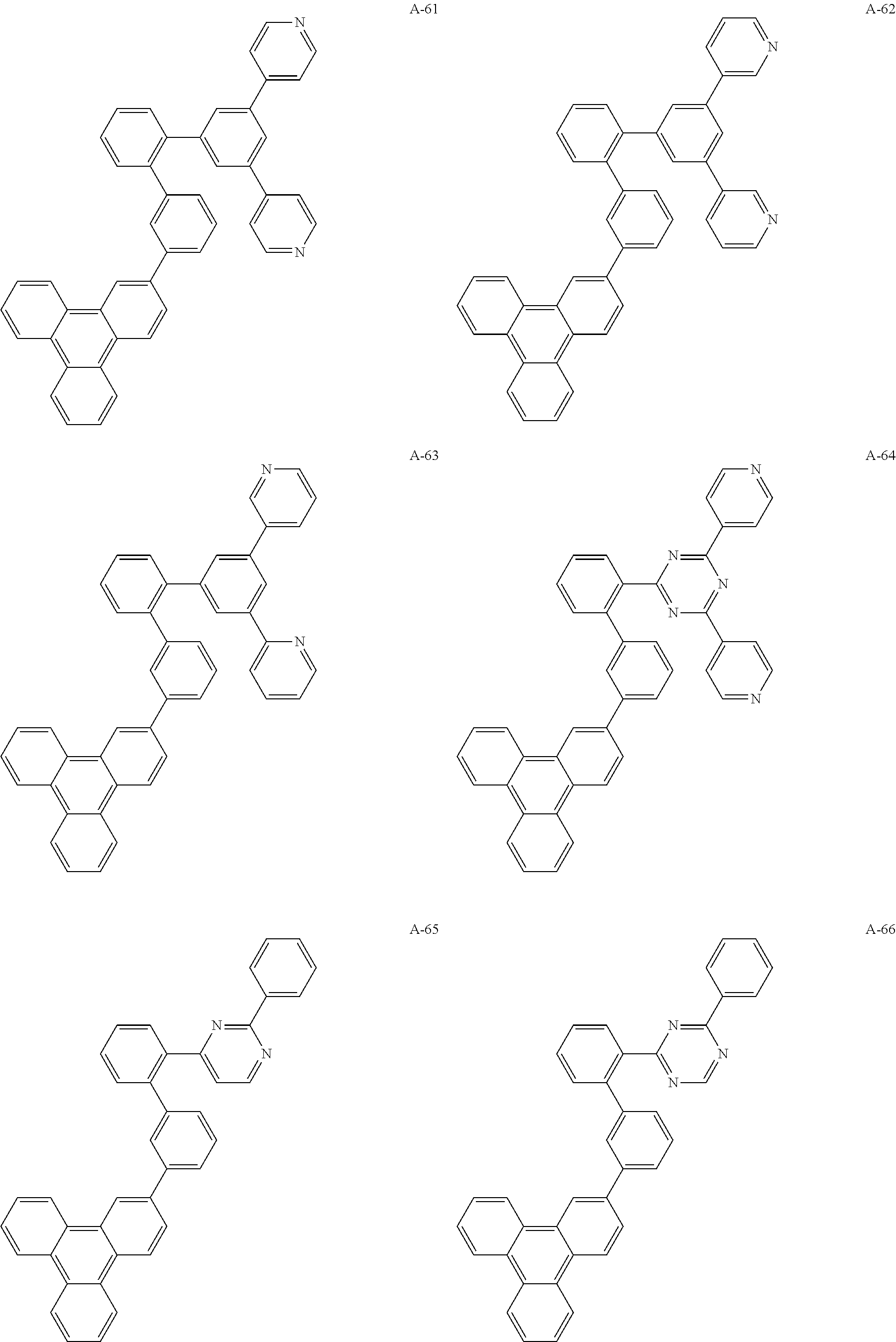 [SMILES: c1cc(-c2ccc3c4ccccc4c4ccccc4c3c2)cc(-c2ccccc2-c2cc(-c3ccncc3)cc(-c3ccncc3)c2)c1 ; c1cncc(-c2cc(-c3cccnc3)cc(-c3ccccc3-c3cccc(-c4ccc5c6ccccc6c6ccccc6c5c4)c3)c2)c1 ; c1ccc(-c2cc(-c3cccnc3)cc(-c3ccccc3-c3cccc(-c4ccc5c6ccccc6c6ccccc6c5c4)c3)c2)nc1 ; c1cc(-c2ccc3c4ccccc4c4ccccc4c3c2)cc(-c2ccccc2-c2nc(-c3ccncc3)nc(-c3ccncc3)n2)c1 ; c1ccc(-c2nccc(-c3ccccc3-c3cccc(-c4ccc5c6ccccc6c6ccccc6c5c4)c3)n2)cc1 ; c1ccc(-c2ncnc(-c3ccccc3-c3cccc(-c4ccc5c6ccccc6c6ccccc6c5c4)c3)n2)cc1]

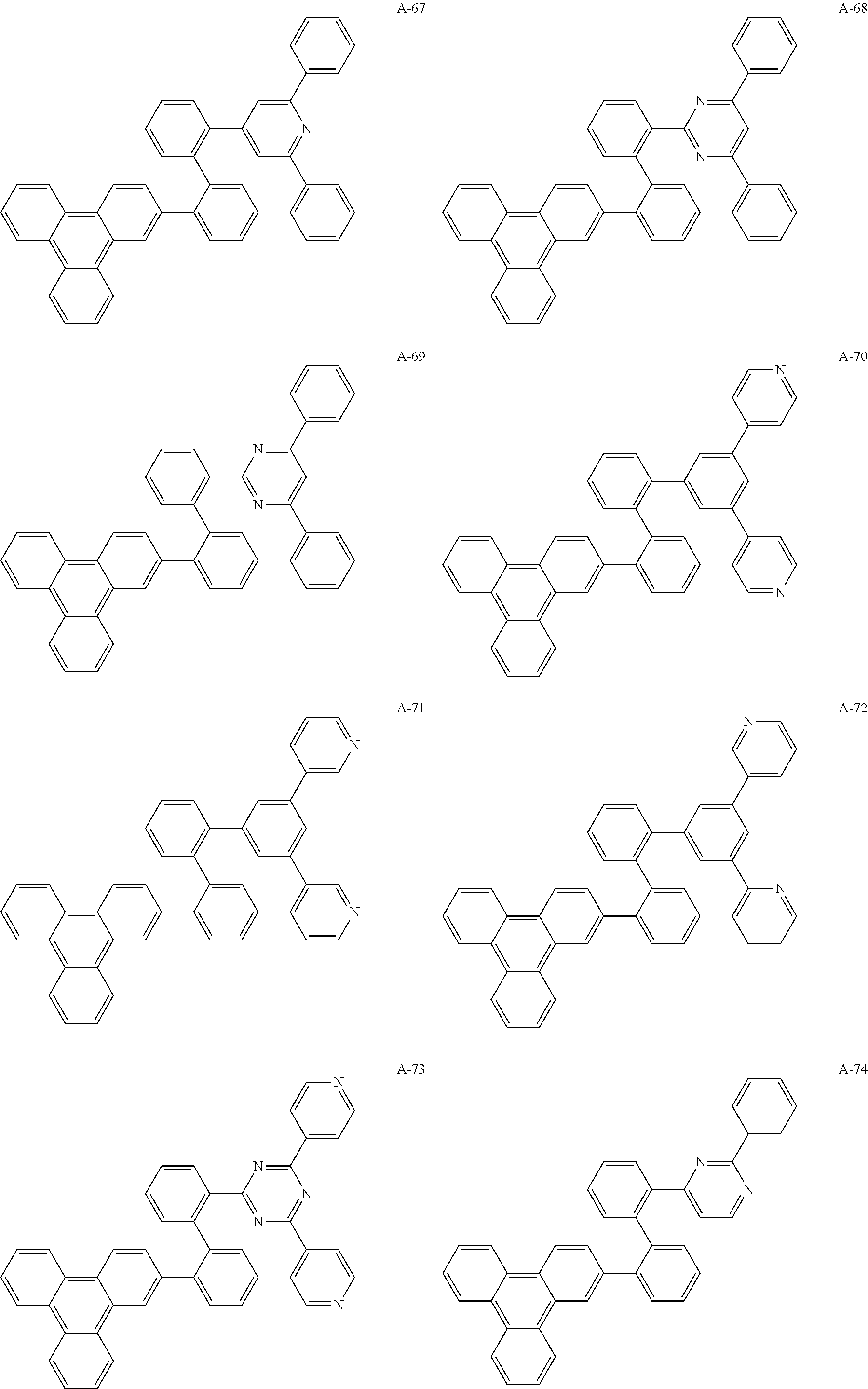

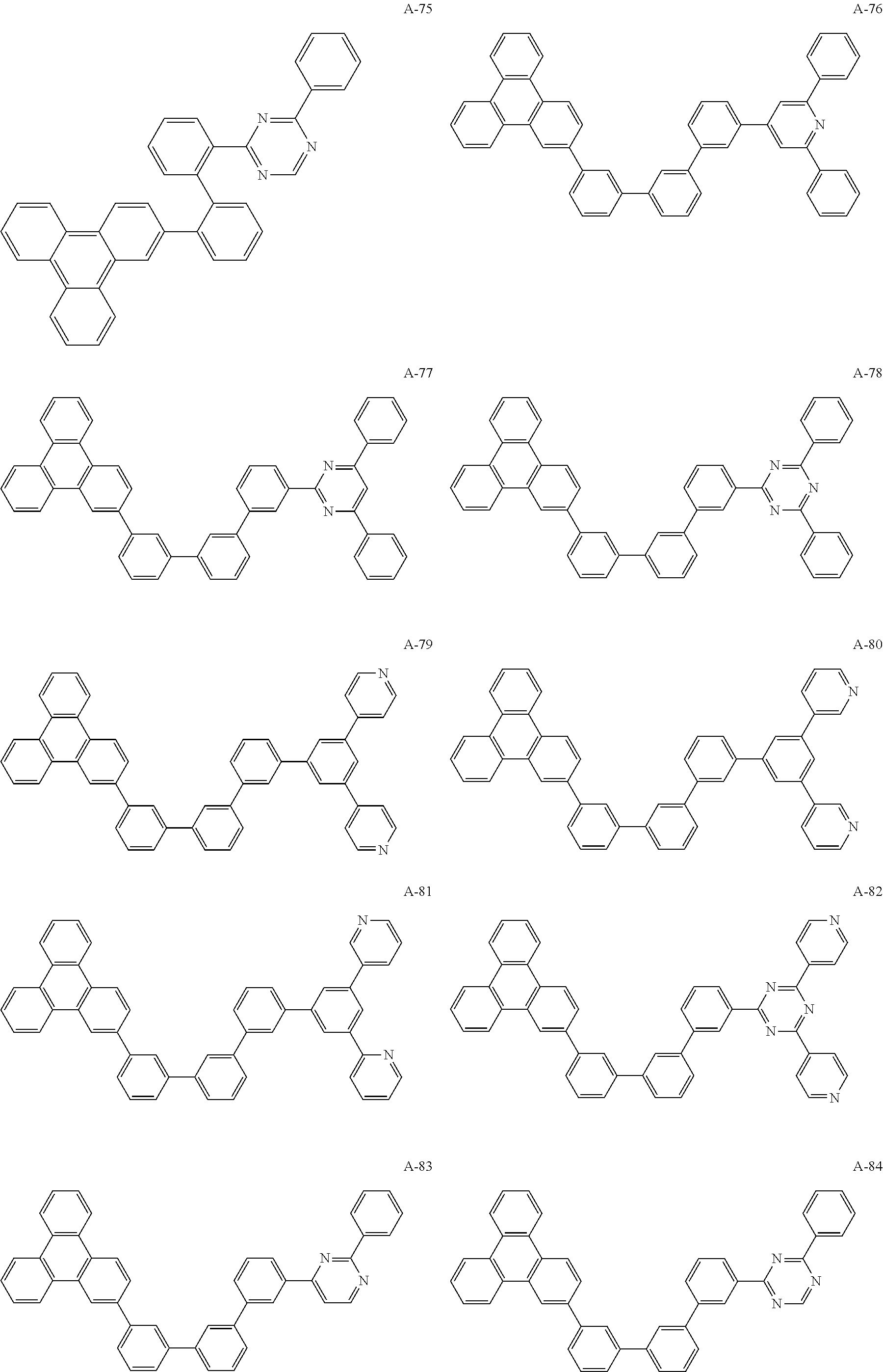

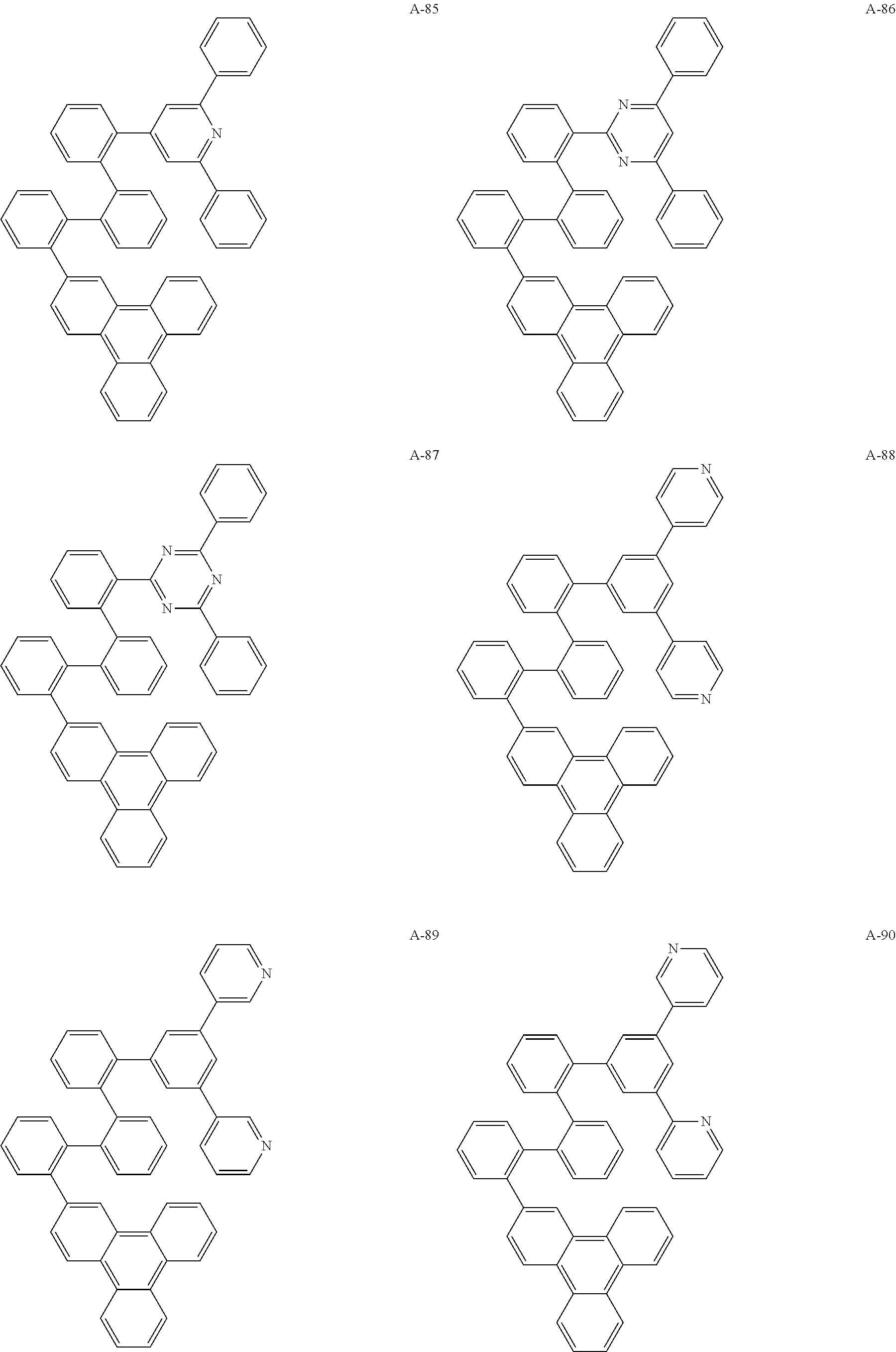

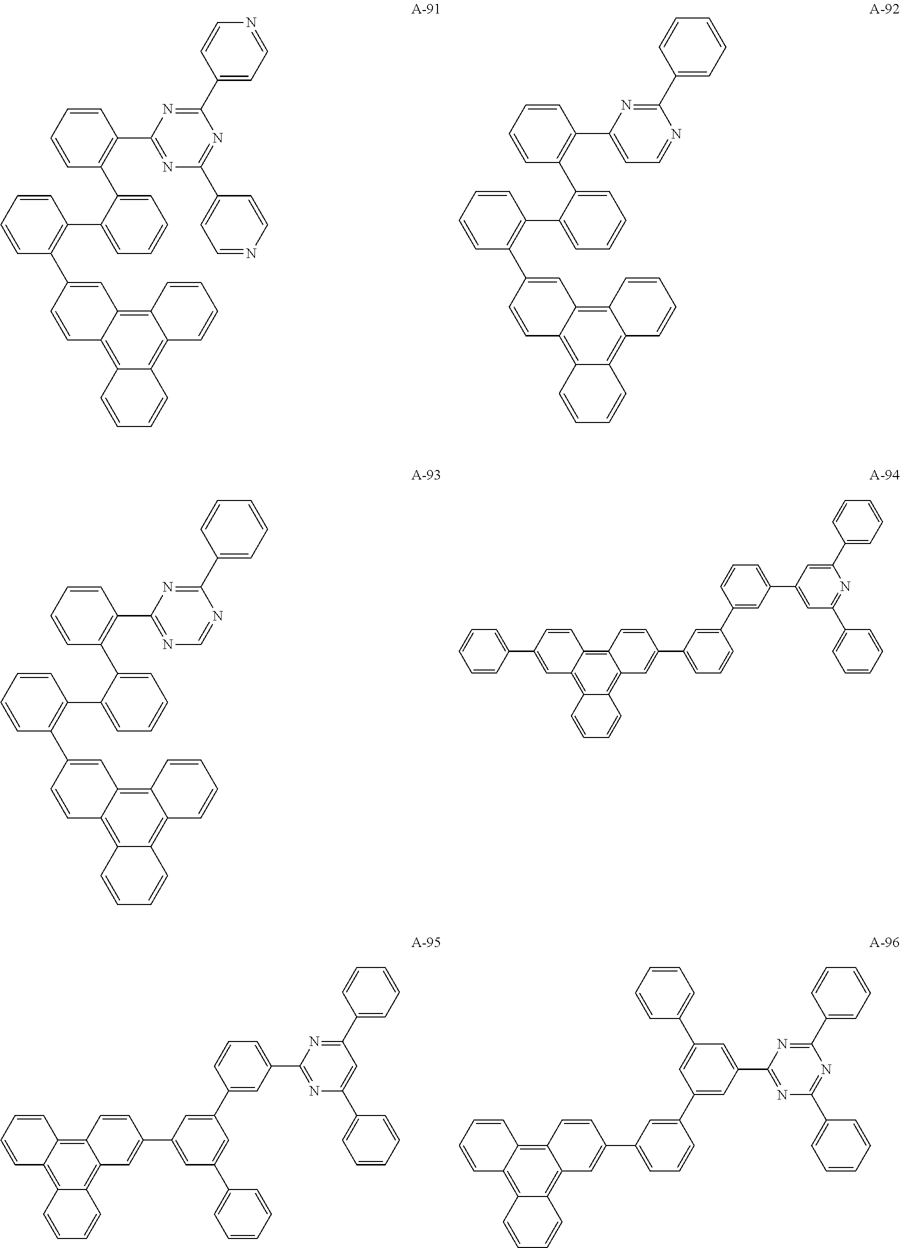

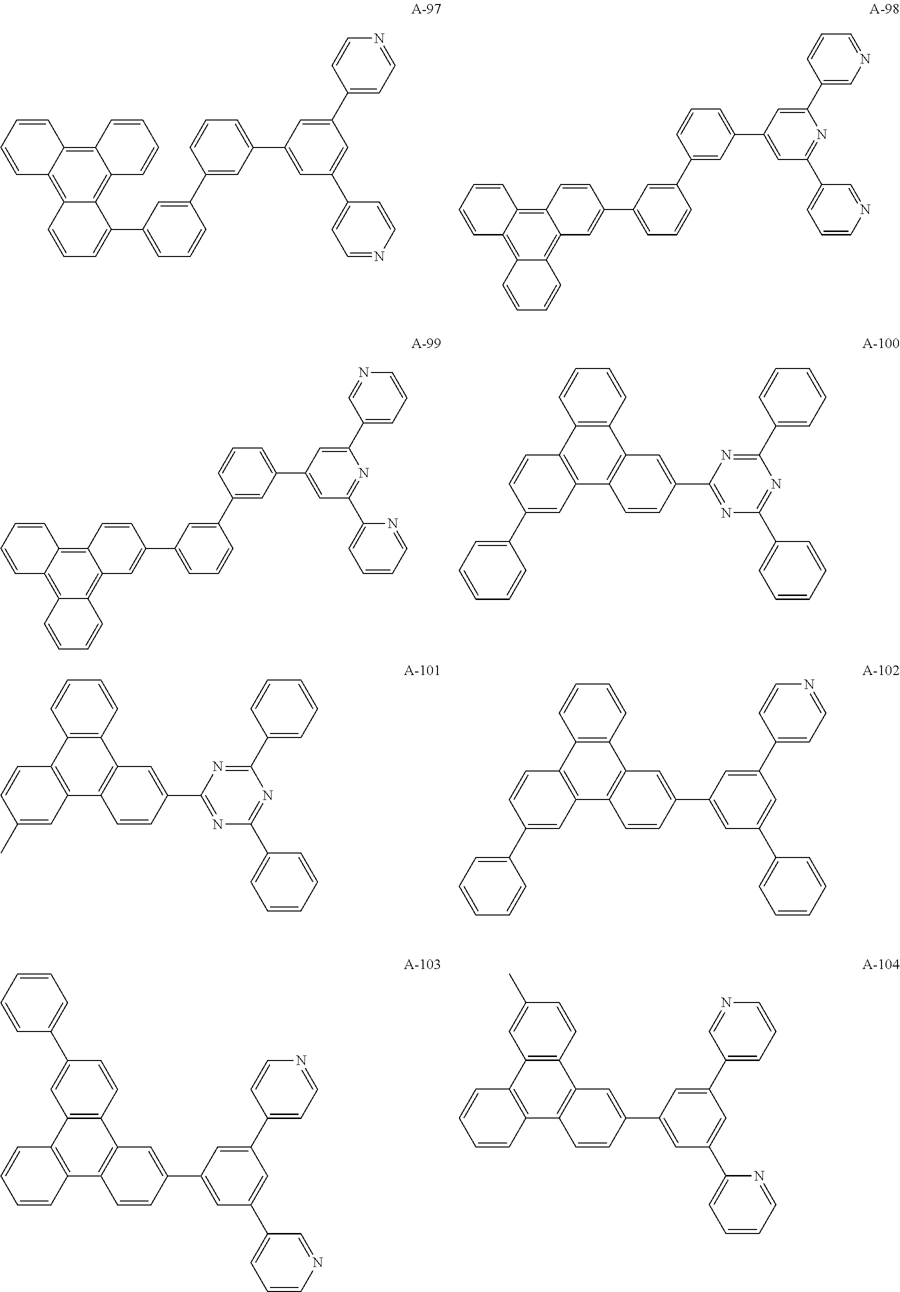

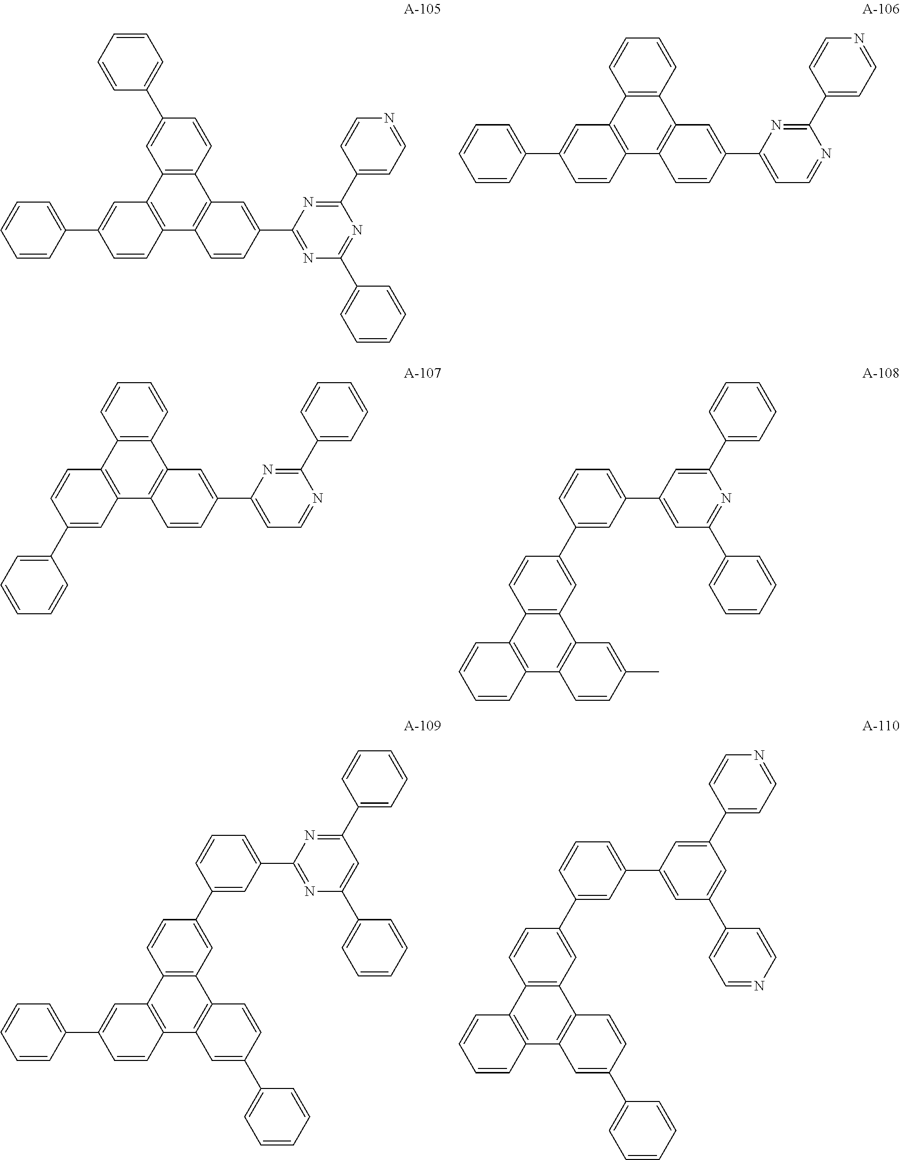

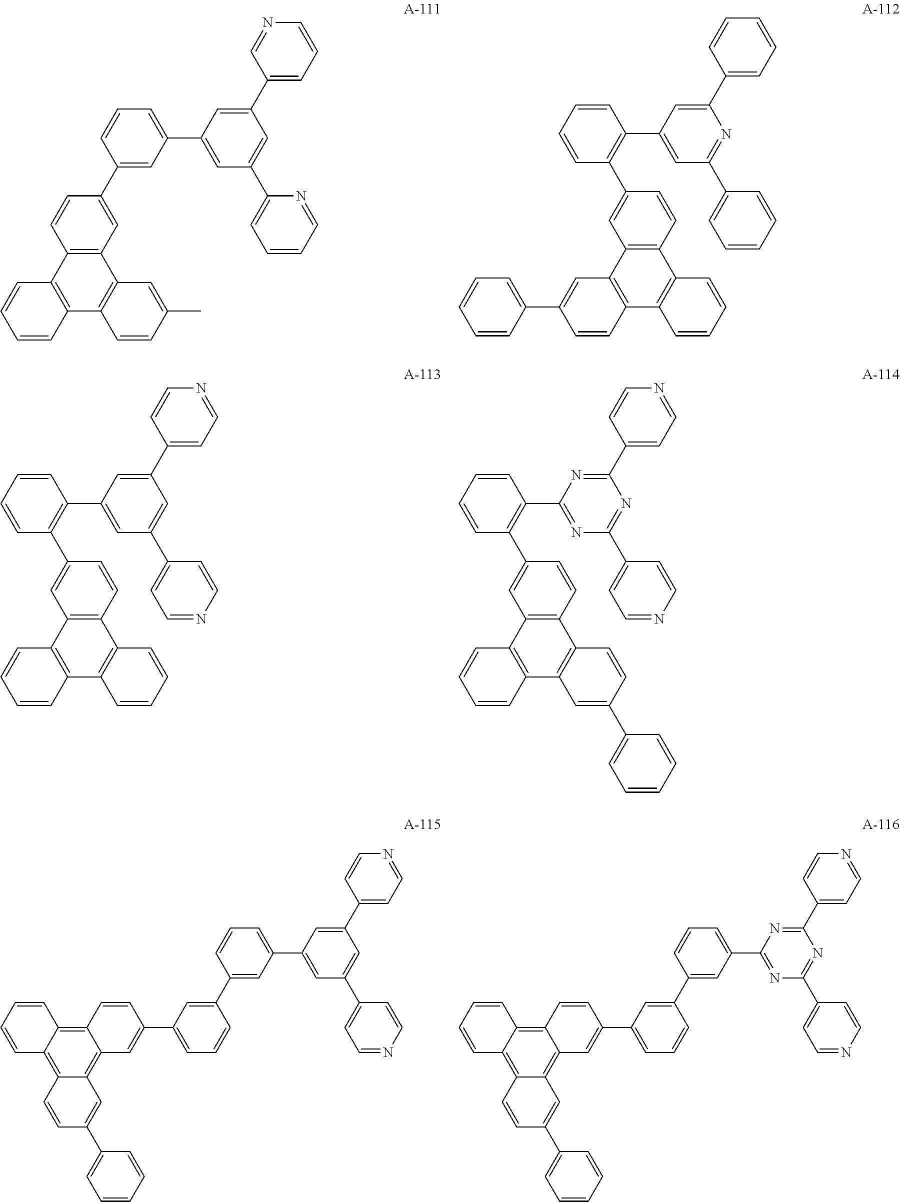 [SMILES: Cc1ccc2c3ccccc3c3ccc(-c4cccc(-c5cc(-c6cccnc6)cc(-c6ccccn6)c5)c4)cc3c2c1 ; c1ccc(-c2ccc3c4ccccc4c4ccc(-c5ccccc5-c5cc(-c6ccccc6)nc(-c6ccccc6)c5)cc4c3c2)cc1 ; c1ccc(-c2ccc3c4ccccc4c4ccccc4c3c2)c(-c2cc(-c3ccncc3)cc(-c3ccncc3)c2)c1 ; c1ccc(-c2ccc3c4ccc(-c5ccccc5-c5nc(-c6ccncc6)nc(-c6ccncc6)n5)cc4c4ccccc4c3c2)cc1 ; c1ccc(-c2ccc3c4ccccc4c4ccc(-c5cccc(-c6cccc(-c7cc(-c8ccncc8)cc(-c8ccncc8)c7)c6)c5)cc4c3c2)cc1 ; c1ccc(-c2ccc3c4ccccc4c4ccc(-c5cccc(-c6cccc(-c7nc(-c8ccncc8)nc(-c8ccncc8)n7)c6)c5)cc4c3c2)cc1]

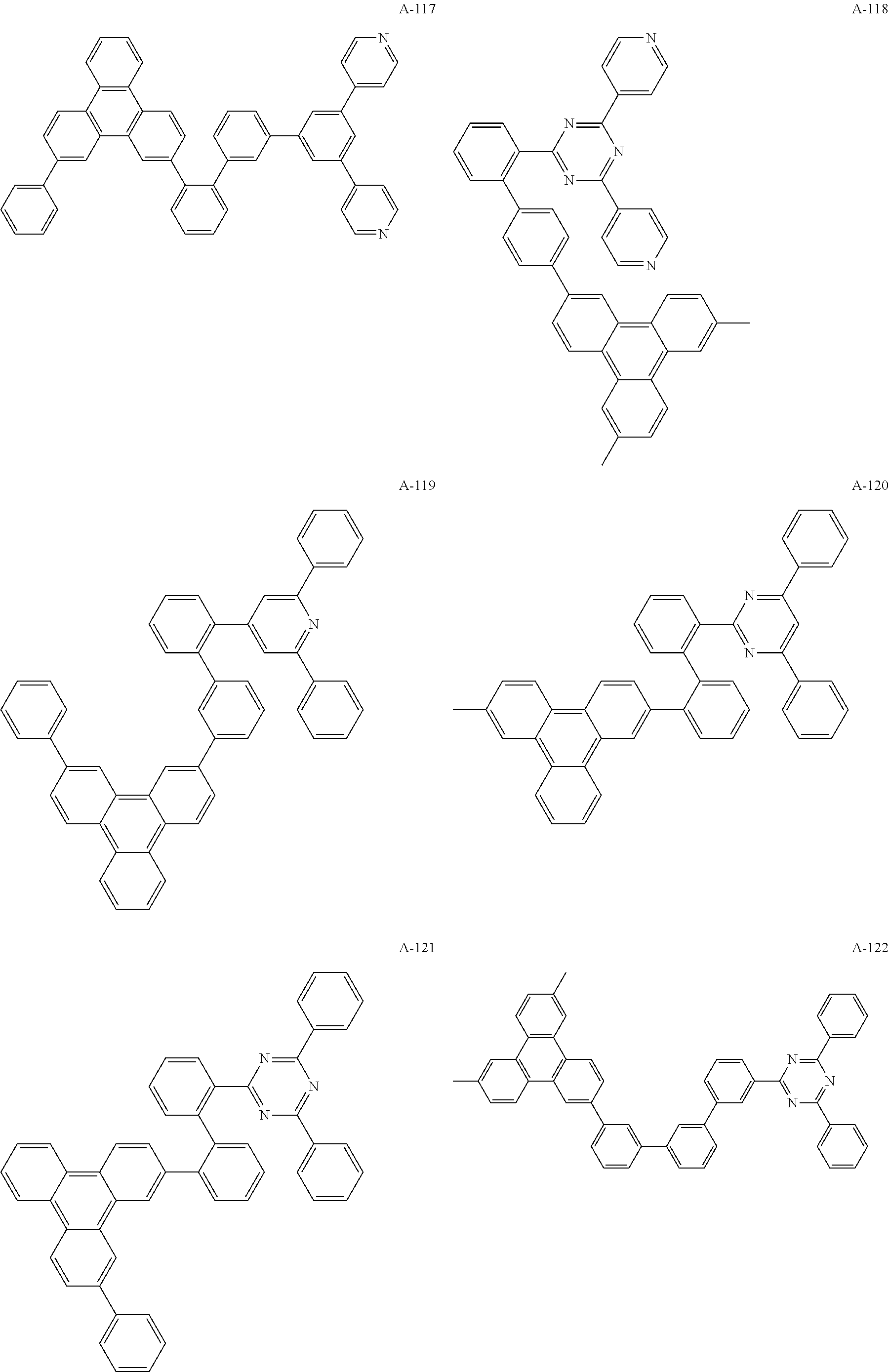

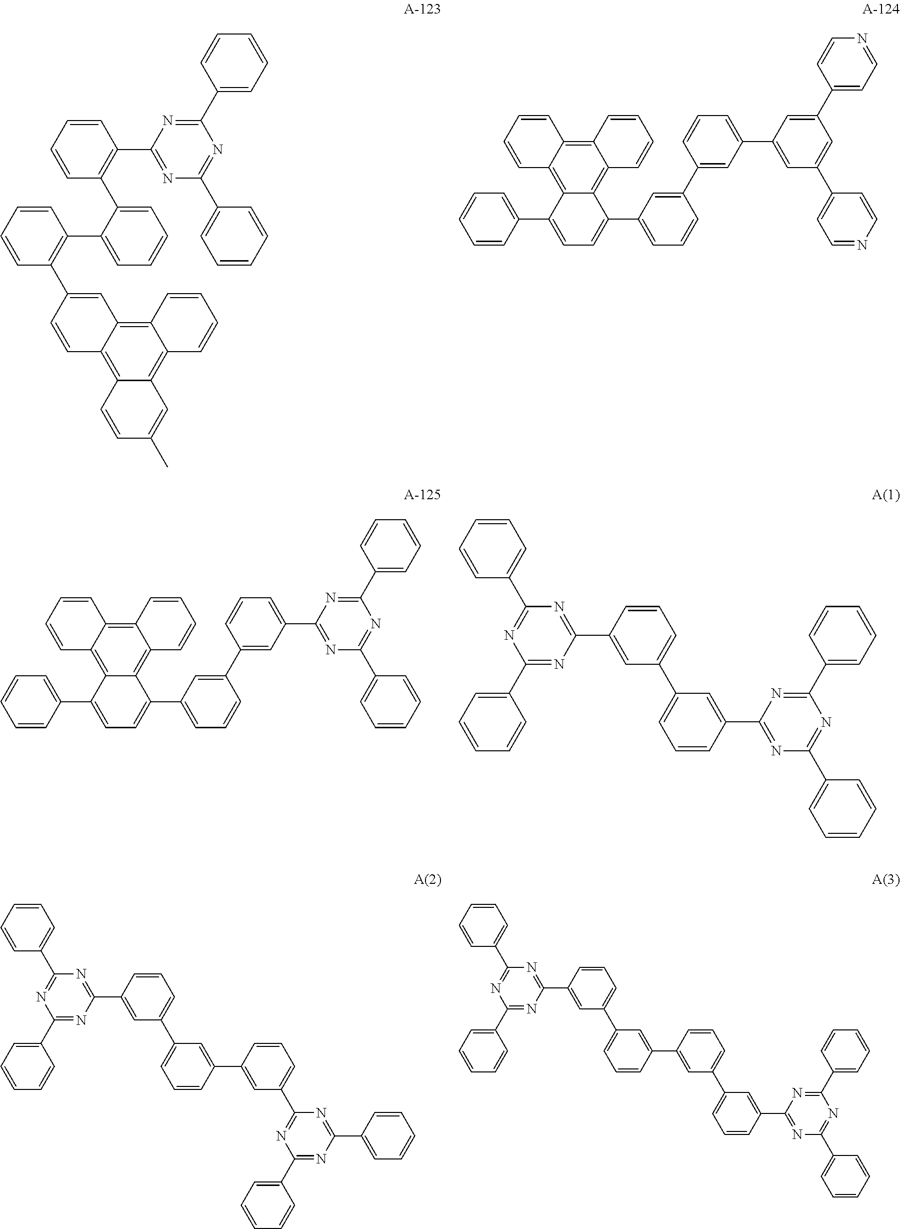

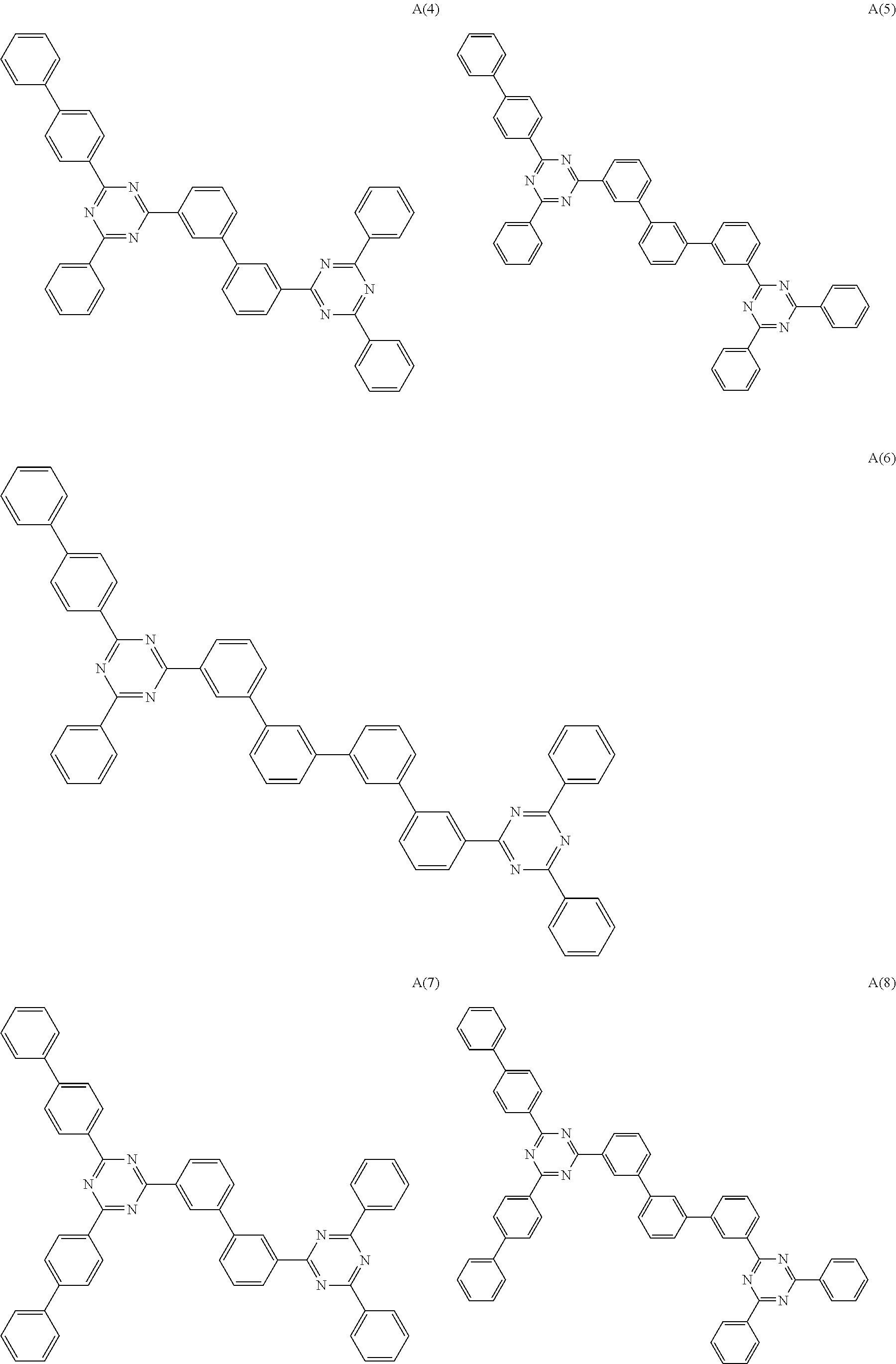

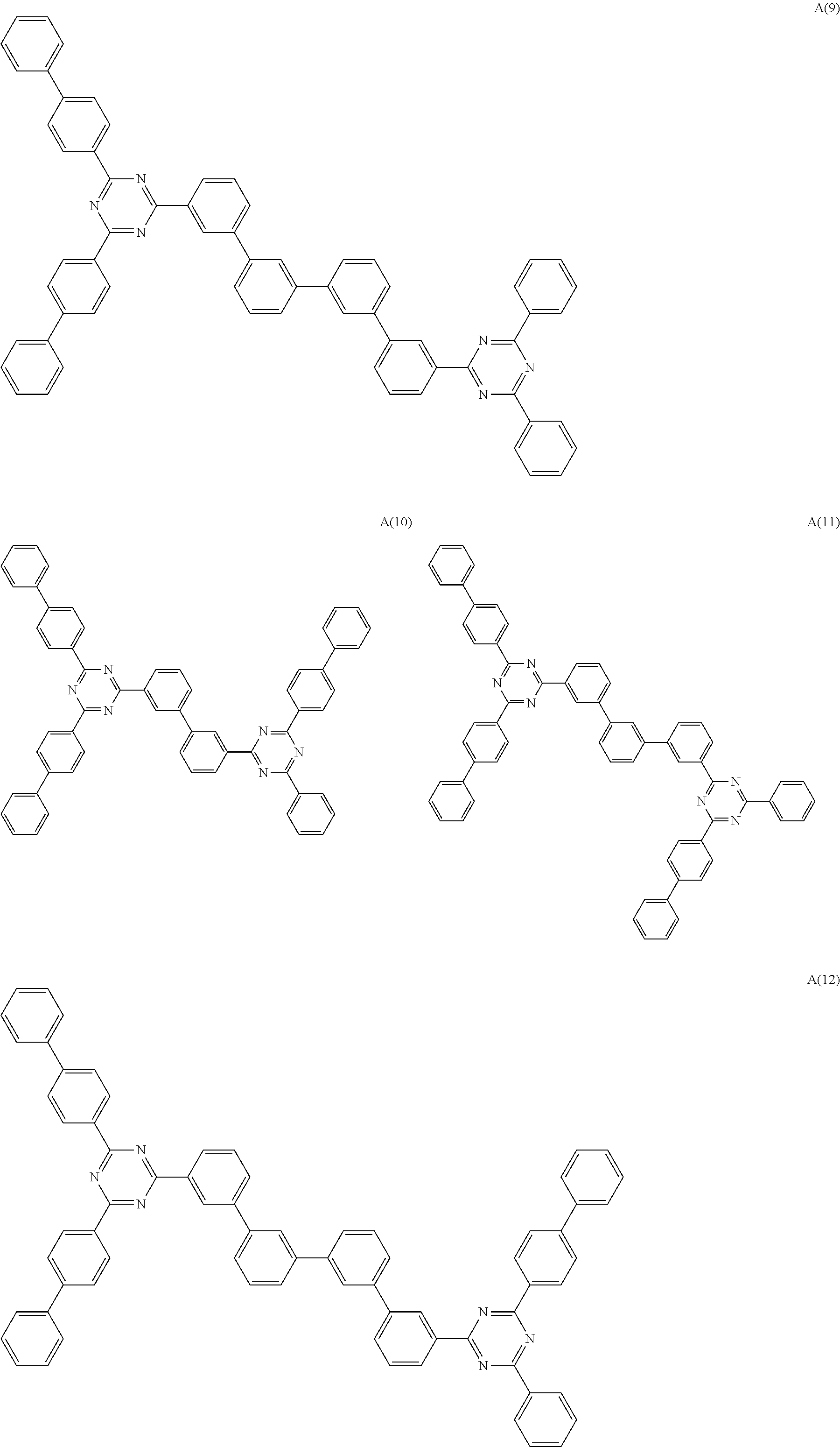

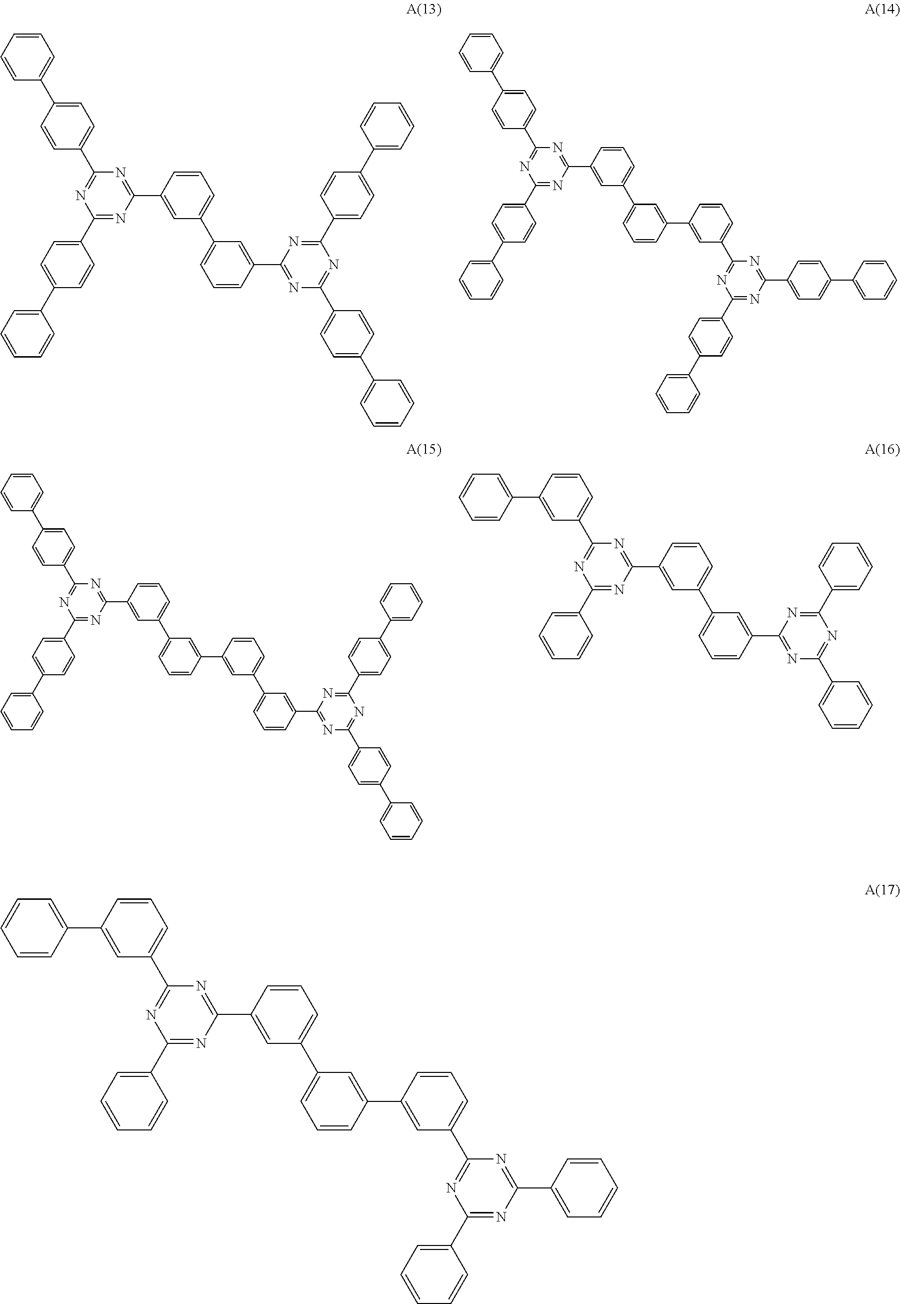

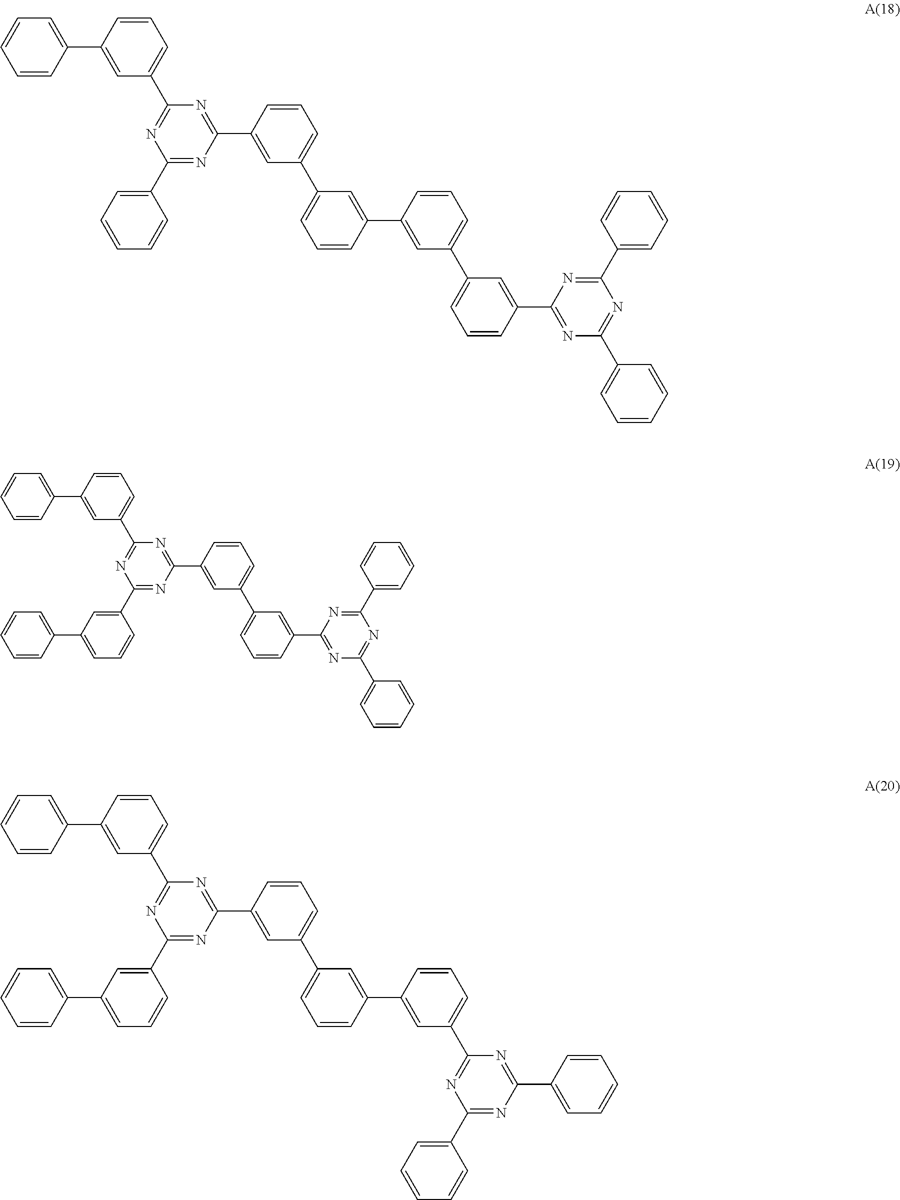 [SMILES: c1ccc(-c2cccc(-c3nc(-c4ccccc4)nc(-c4cccc(-c5cccc(-c6cccc(-c7cccc(-c8nc(-c9ccccc9)nc(-c9ccccc9)n8)c7)c6)c5)c4)n3)c2)cc1 ; c1ccc(-c2cccc(-c3nc(-c4cccc(-c5ccccc5)c4)nc(-c4cccc(-c5cccc(-c6nc(-c7ccccc7)nc(-c7ccccc7)n6)c5)c4)n3)c2)cc1 ; c1ccc(-c2cccc(-c3nc(-c4cccc(-c5ccccc5)c4)nc(-c4cccc(-c5cccc(-c6cccc(-c7nc(-c8ccccc8)nc(-c8ccccc8)n7)c6)c5)c4)n3)c2)cc1]

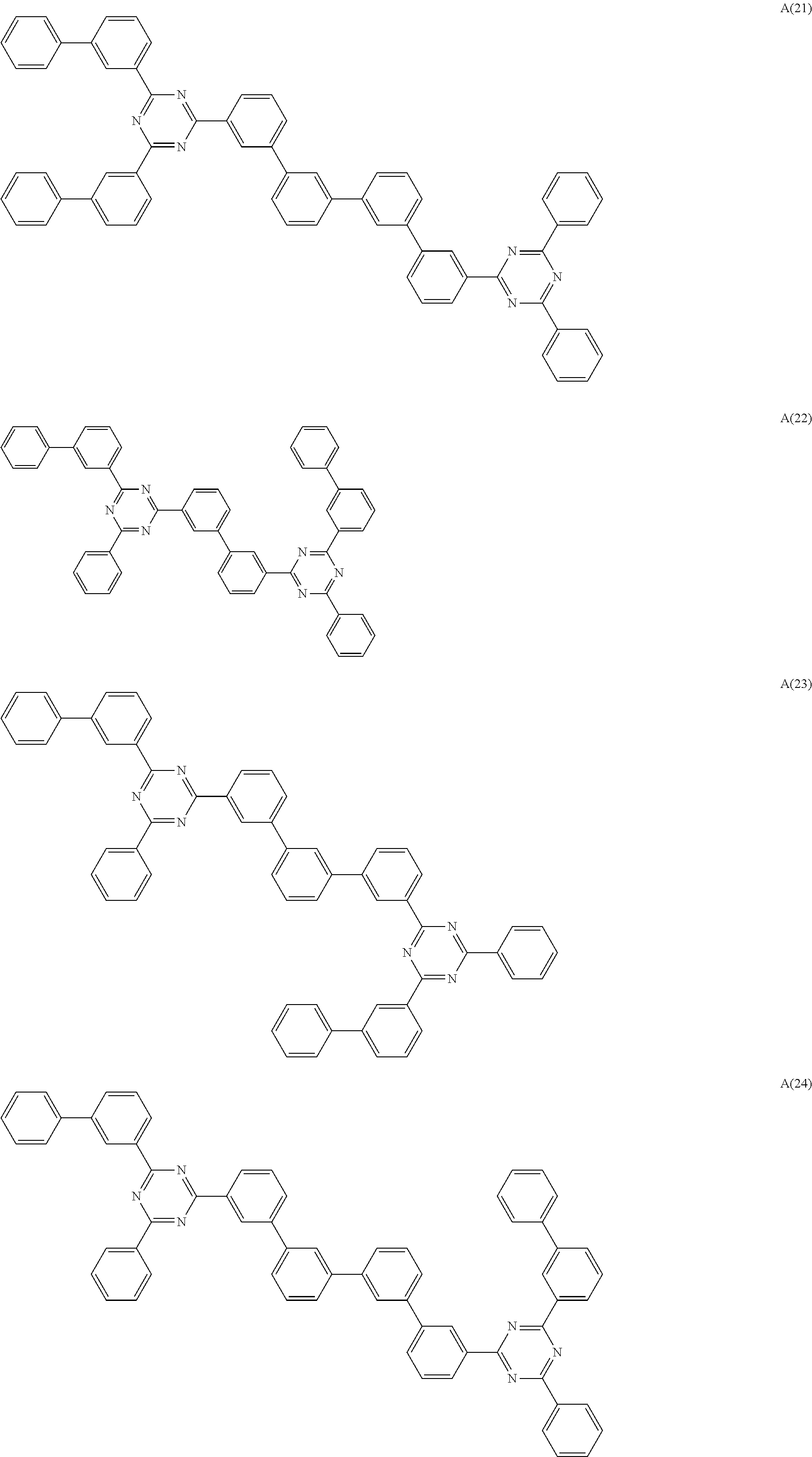 [SMILES: c1ccc(-c2cccc(-c3nc(-c4cccc(-c5ccccc5)c4)nc(-c4cccc(-c5cccc(-c6cccc(-c7cccc(-c8nc(-c9ccccc9)nc(-c9ccccc9)n8)c7)c6)c5)c4)n3)c2)cc1 ; c1ccc(-c2cccc(-c3nc(-c4ccccc4)nc(-c4cccc(-c5cccc(-c6nc(-c7ccccc7)nc(-c7cccc(-c8ccccc8)c7)n6)c5)c4)n3)c2)cc1 ; c1ccc(-c2cccc(-c3nc(-c4ccccc4)nc(-c4cccc(-c5cccc(-c6cccc(-c7nc(-c8ccccc8)nc(-c8cccc(-c9ccccc9)c8)n7)c6)c5)c4)n3)c2)cc1 ; c1ccc(-c2cccc(-c3nc(-c4ccccc4)nc(-c4cccc(-c5cccc(-c6cccc(-c7cccc(-c8nc(-c9ccccc9)nc(-c9cccc(-c%10ccccc%10)c9)n8)c7)c6)c5)c4)n3)c2)cc1]

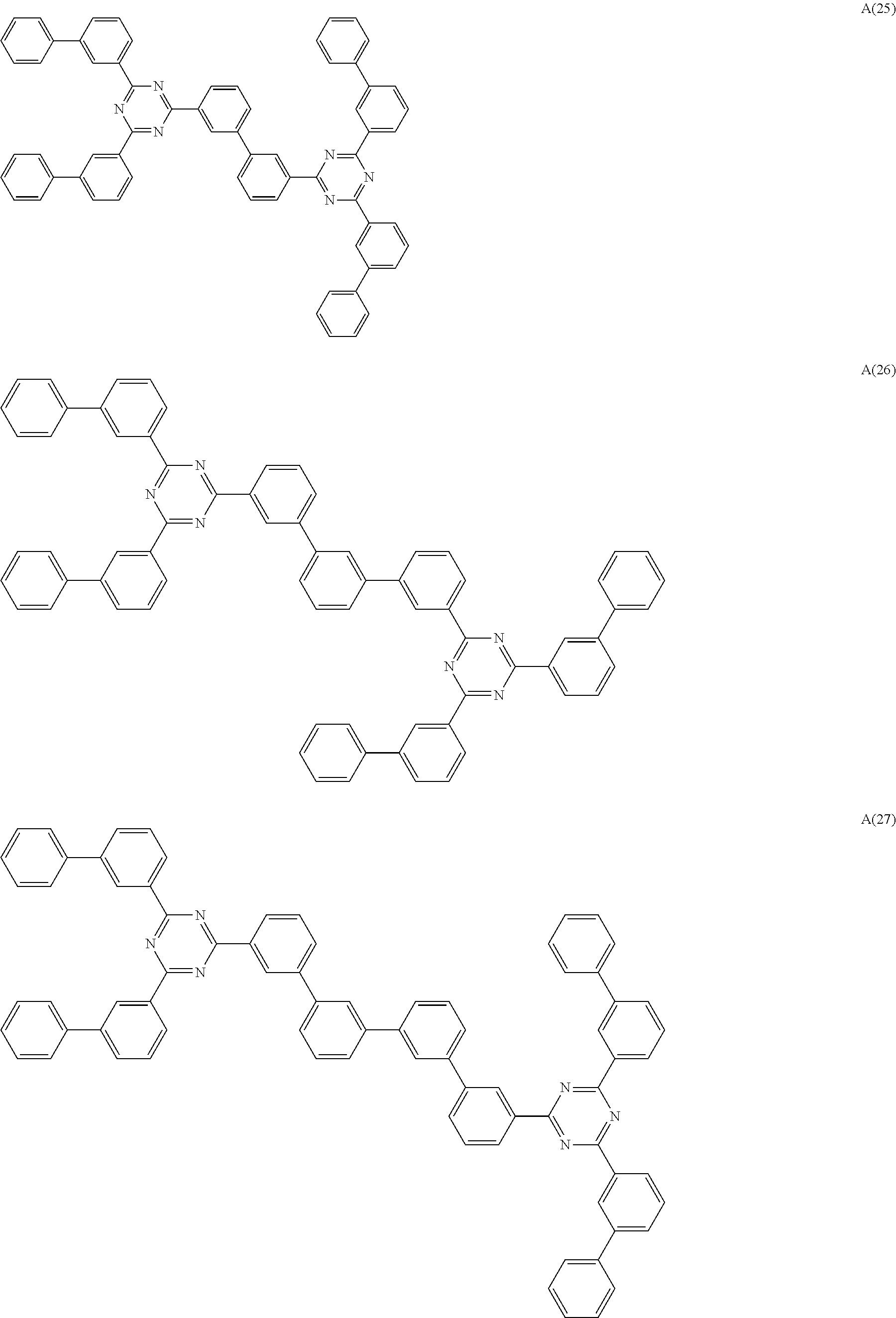 [SMILES: c1ccc(-c2cccc(-c3nc(-c4cccc(-c5ccccc5)c4)nc(-c4cccc(-c5cccc(-c6nc(-c7cccc(-c8ccccc8)c7)nc(-c7cccc(-c8ccccc8)c7)n6)c5)c4)n3)c2)cc1 ; c1ccc(-c2cccc(-c3nc(-c4cccc(-c5ccccc5)c4)nc(-c4cccc(-c5cccc(-c6cccc(-c7nc(-c8cccc(-c9ccccc9)c8)nc(-c8cccc(-c9ccccc9)c8)n7)c6)c5)c4)n3)c2)cc1 ; c1ccc(-c2cccc(-c3nc(-c4cccc(-c5ccccc5)c4)nc(-c4cccc(-c5cccc(-c6cccc(-c7cccc(-c8nc(-c9cccc(-c%10ccccc%10)c9)nc(-c9cccc(-c%10ccccc%10)c9)n8)c7)c6)c5)c4)n3)c2)cc1]

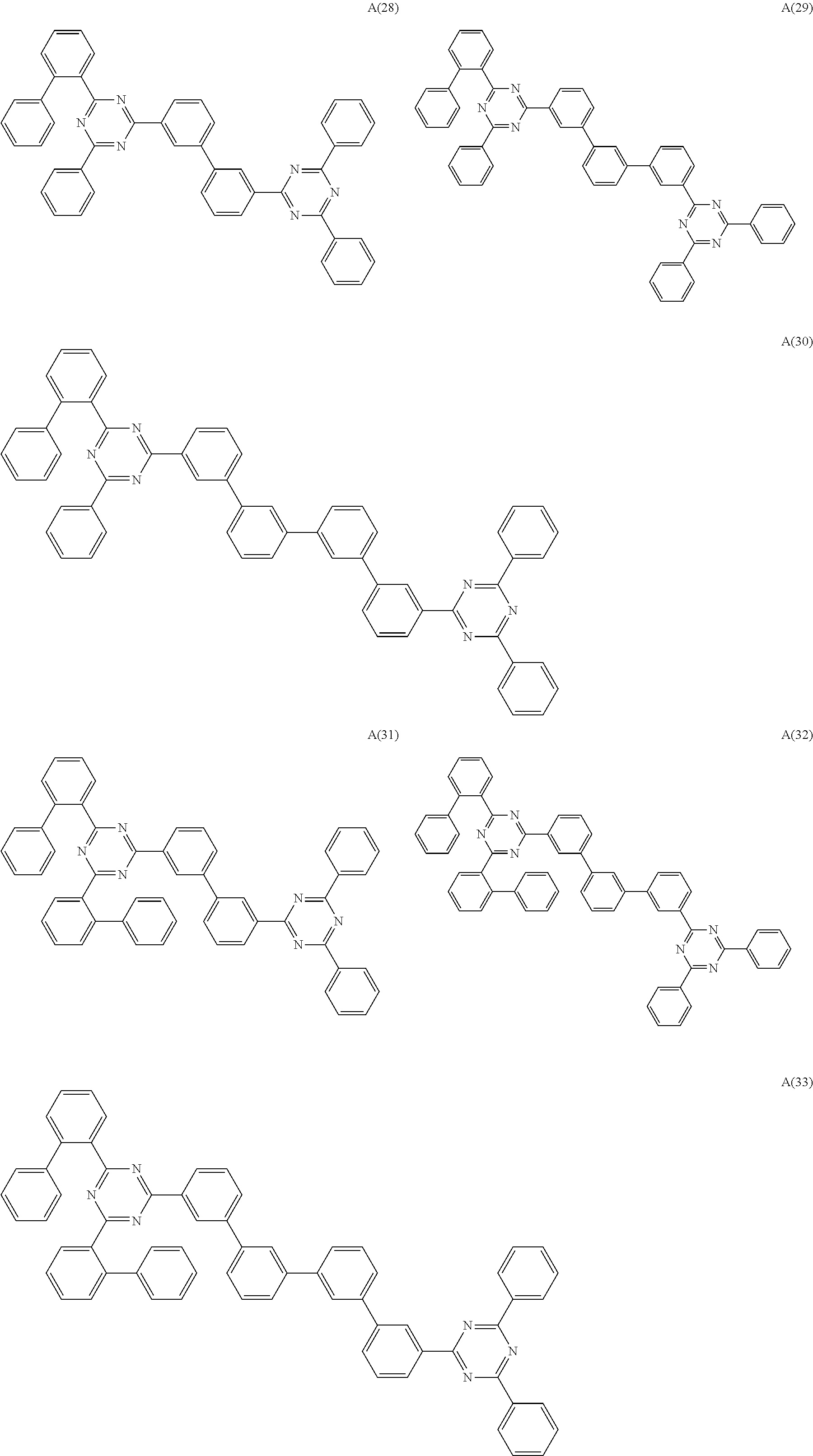

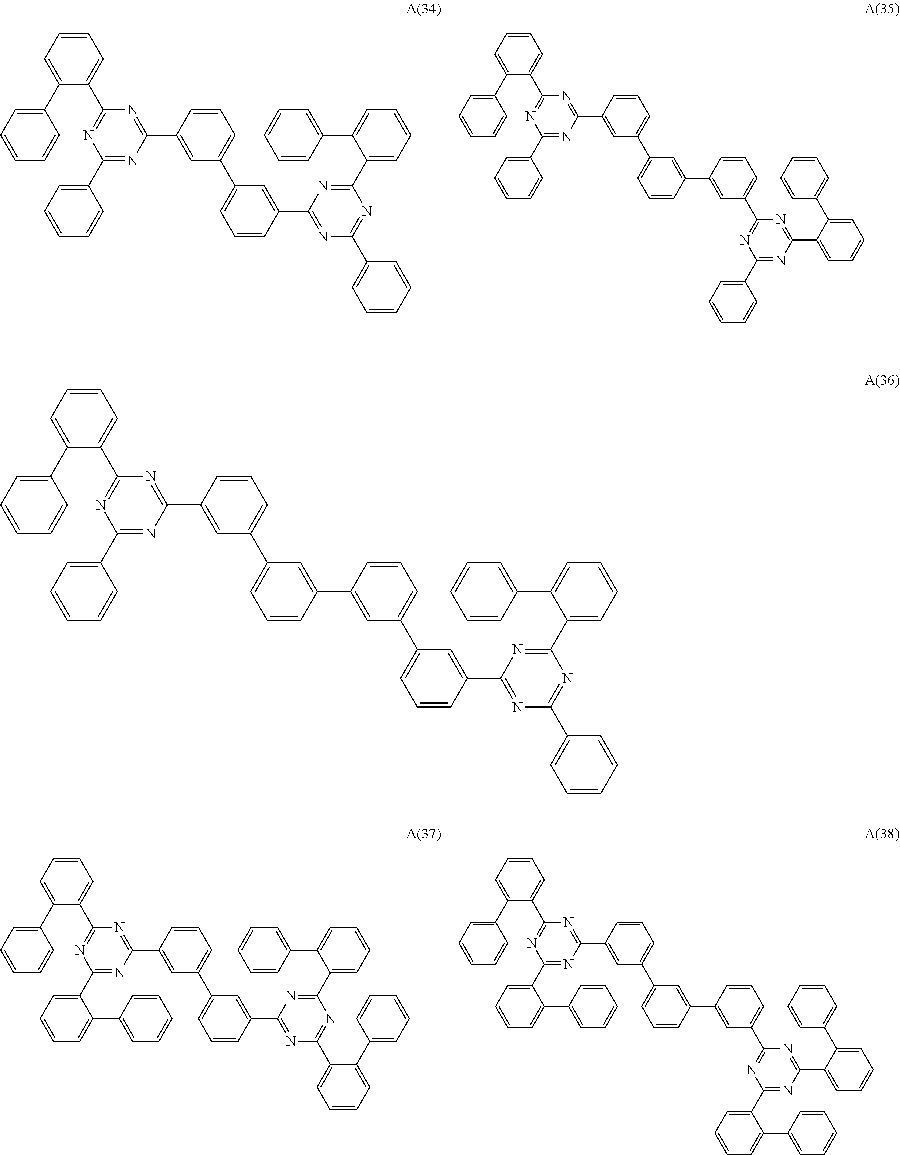

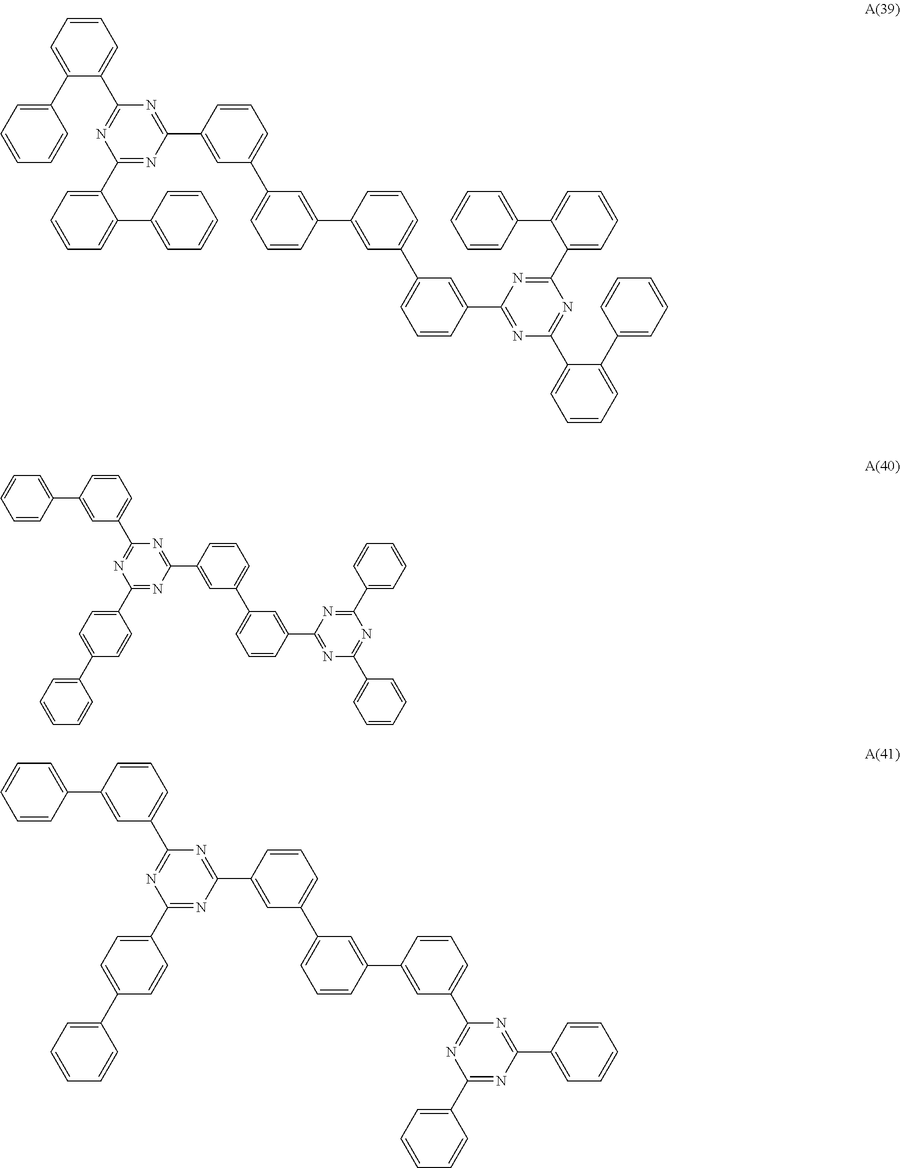

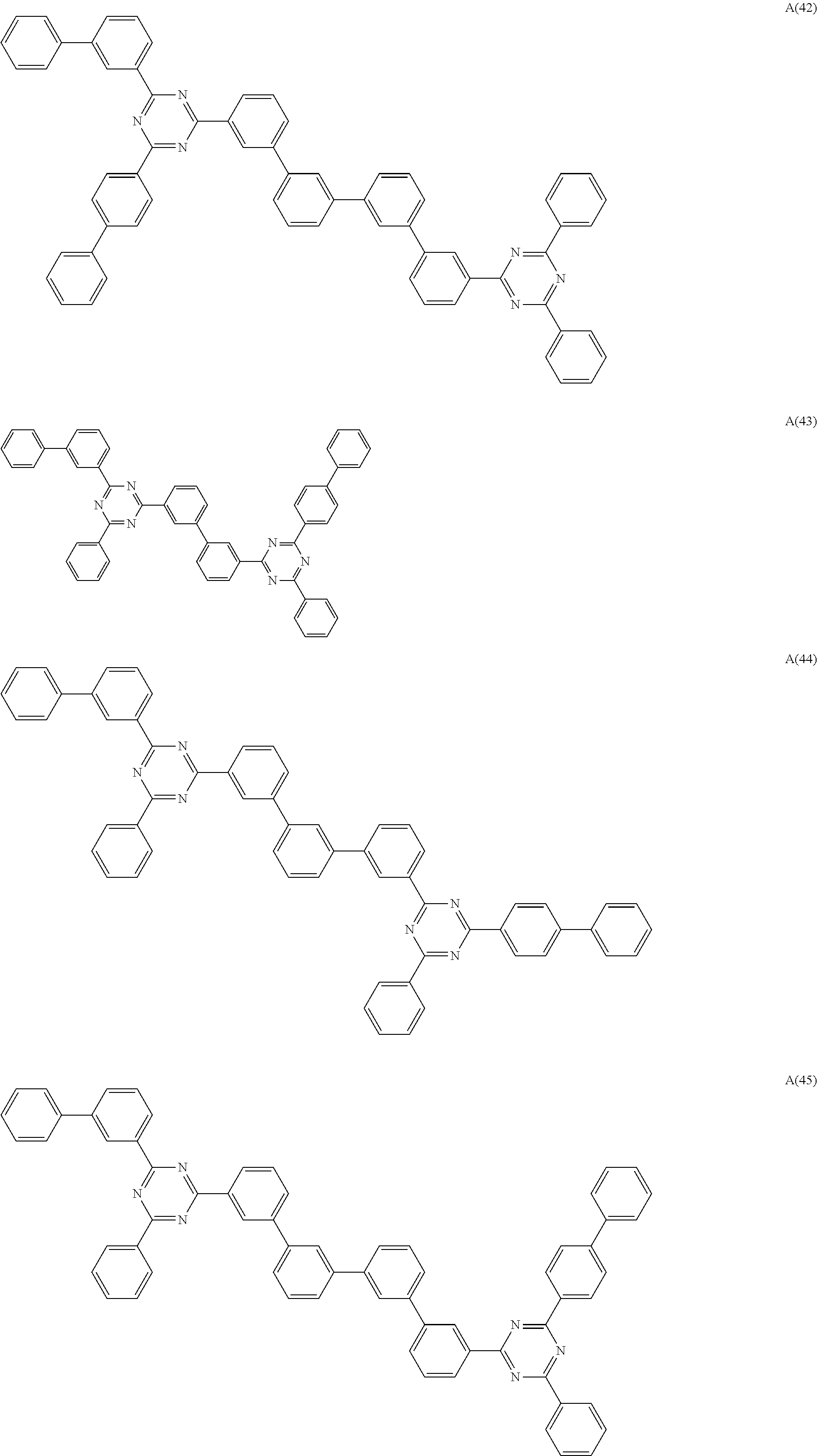 [SMILES: c1ccc(-c2ccc(-c3nc(-c4cccc(-c5ccccc5)c4)nc(-c4cccc(-c5cccc(-c6cccc(-c7cccc(-c8nc(-c9ccccc9)nc(-c9ccccc9)n8)c7)c6)c5)c4)n3)cc2)cc1 ; c1ccc(-c2ccc(-c3nc(-c4ccccc4)nc(-c4cccc(-c5cccc(-c6nc(-c7ccccc7)nc(-c7cccc(-c8ccccc8)c7)n6)c5)c4)n3)cc2)cc1 ; c1ccc(-c2ccc(-c3nc(-c4ccccc4)nc(-c4cccc(-c5cccc(-c6cccc(-c7nc(-c8ccccc8)nc(-c8cccc(-c9ccccc9)c8)n7)c6)c5)c4)n3)cc2)cc1 ; c1ccc(-c2ccc(-c3nc(-c4ccccc4)nc(-c4cccc(-c5cccc(-c6cccc(-c7cccc(-c8nc(-c9ccccc9)nc(-c9cccc(-c%10ccccc%10)c9)n8)c7)c6)c5)c4)n3)cc2)cc1]

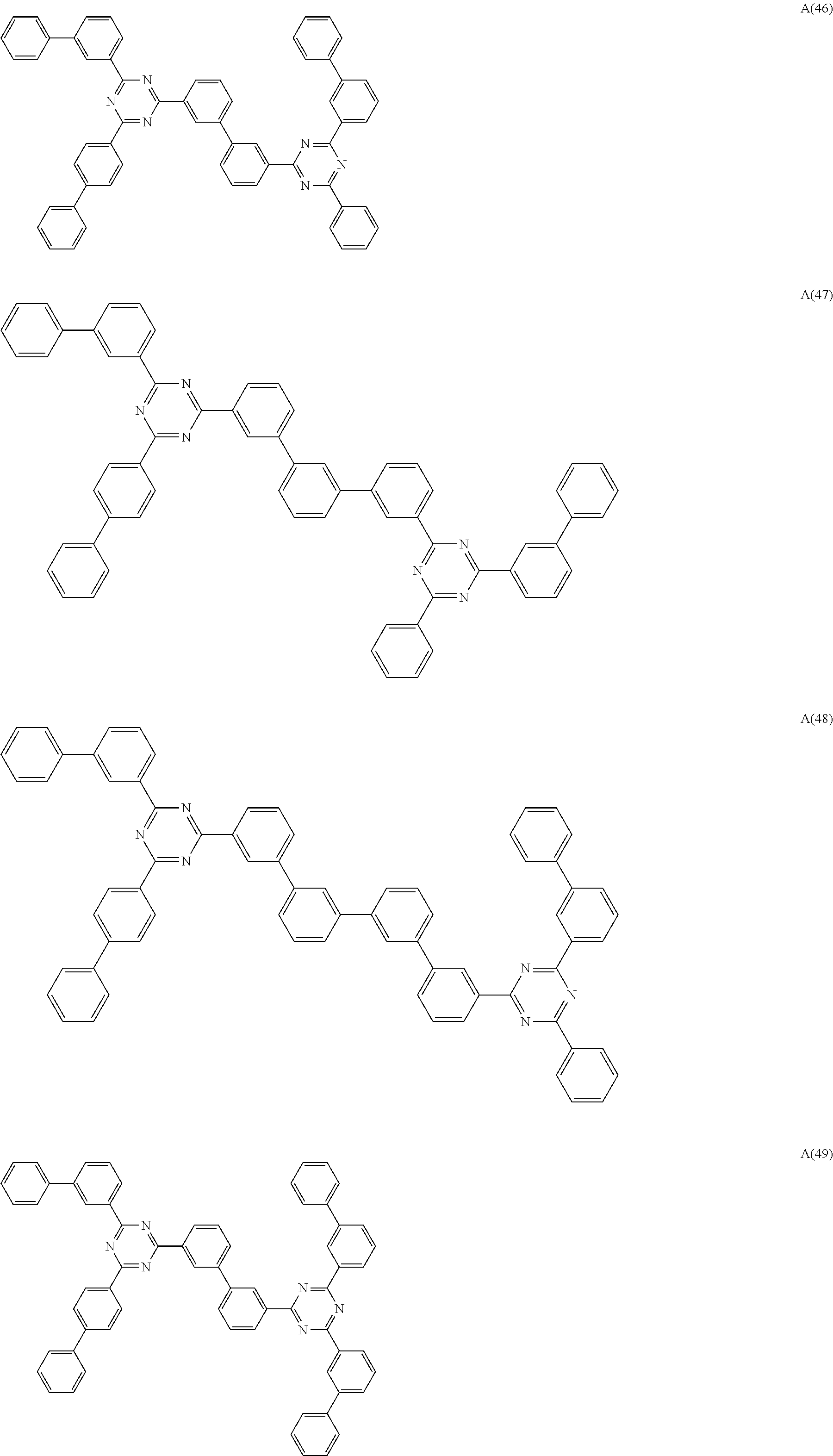

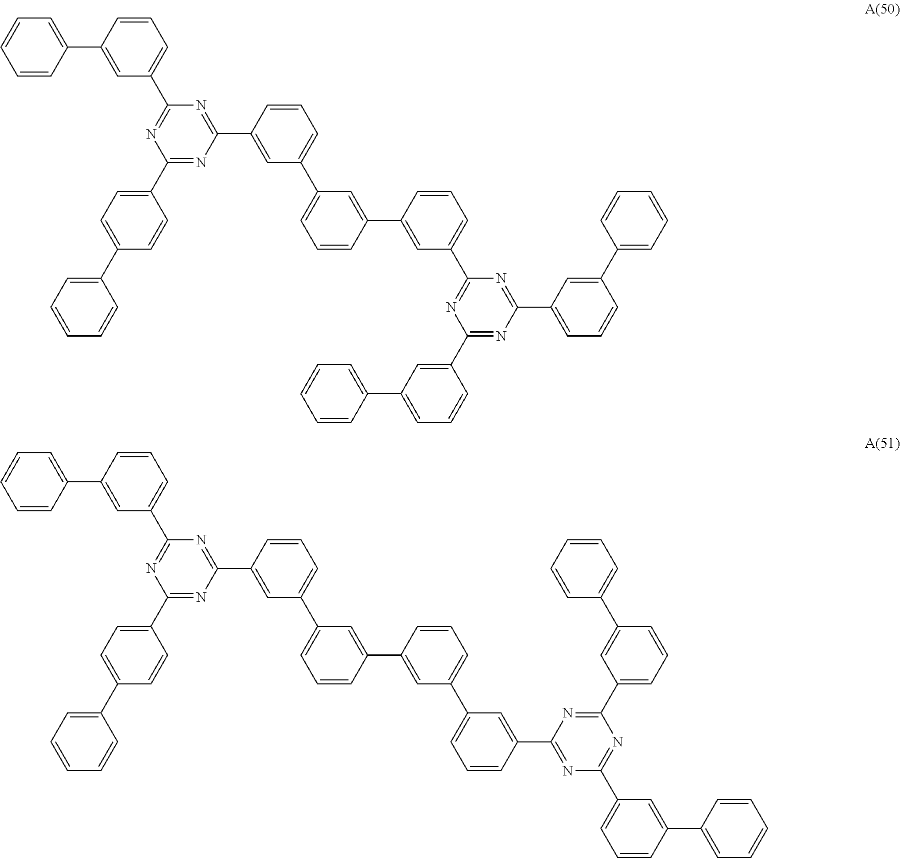 [SMILES: c1ccc(-c2ccc(-c3nc(-c4cccc(-c5ccccc5)c4)nc(-c4cccc(-c5cccc(-c6cccc(-c7nc(-c8cccc(-c9ccccc9)c8)nc(-c8cccc(-c9ccccc9)c8)n7)c6)c5)c4)n3)cc2)cc1 ; c1ccc(-c2ccc(-c3nc(-c4cccc(-c5ccccc5)c4)nc(-c4cccc(-c5cccc(-c6cccc(-c7cccc(-c8nc(-c9cccc(-c%10ccccc%10)c9)nc(-c9cccc(-c%10ccccc%10)c9)n8)c7)c6)c5)c4)n3)cc2)cc1]

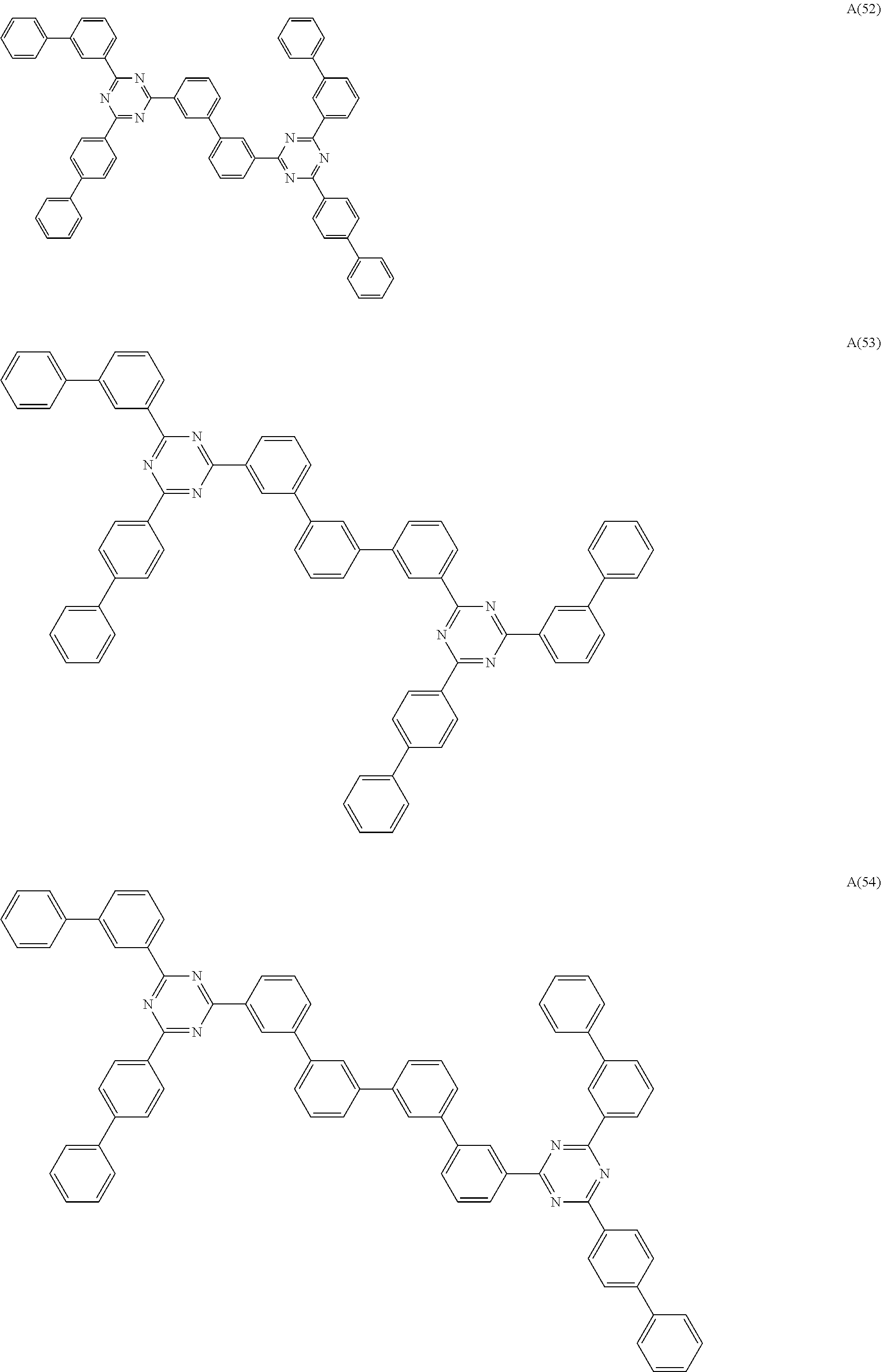 [SMILES: c1ccc(-c2ccc(-c3nc(-c4cccc(-c5ccccc5)c4)nc(-c4cccc(-c5cccc(-c6nc(-c7ccc(-c8ccccc8)cc7)nc(-c7cccc(-c8ccccc8)c7)n6)c5)c4)n3)cc2)cc1 ; c1ccc(-c2ccc(-c3nc(-c4cccc(-c5ccccc5)c4)nc(-c4cccc(-c5cccc(-c6cccc(-c7nc(-c8ccc(-c9ccccc9)cc8)nc(-c8cccc(-c9ccccc9)c8)n7)c6)c5)c4)n3)cc2)cc1 ; c1ccc(-c2ccc(-c3nc(-c4cccc(-c5ccccc5)c4)nc(-c4cccc(-c5cccc(-c6cccc(-c7cccc(-c8nc(-c9ccc(-c%10ccccc%10)cc9)nc(-c9cccc(-c%10ccccc%10)c9)n8)c7)c6)c5)c4)n3)cc2)cc1]

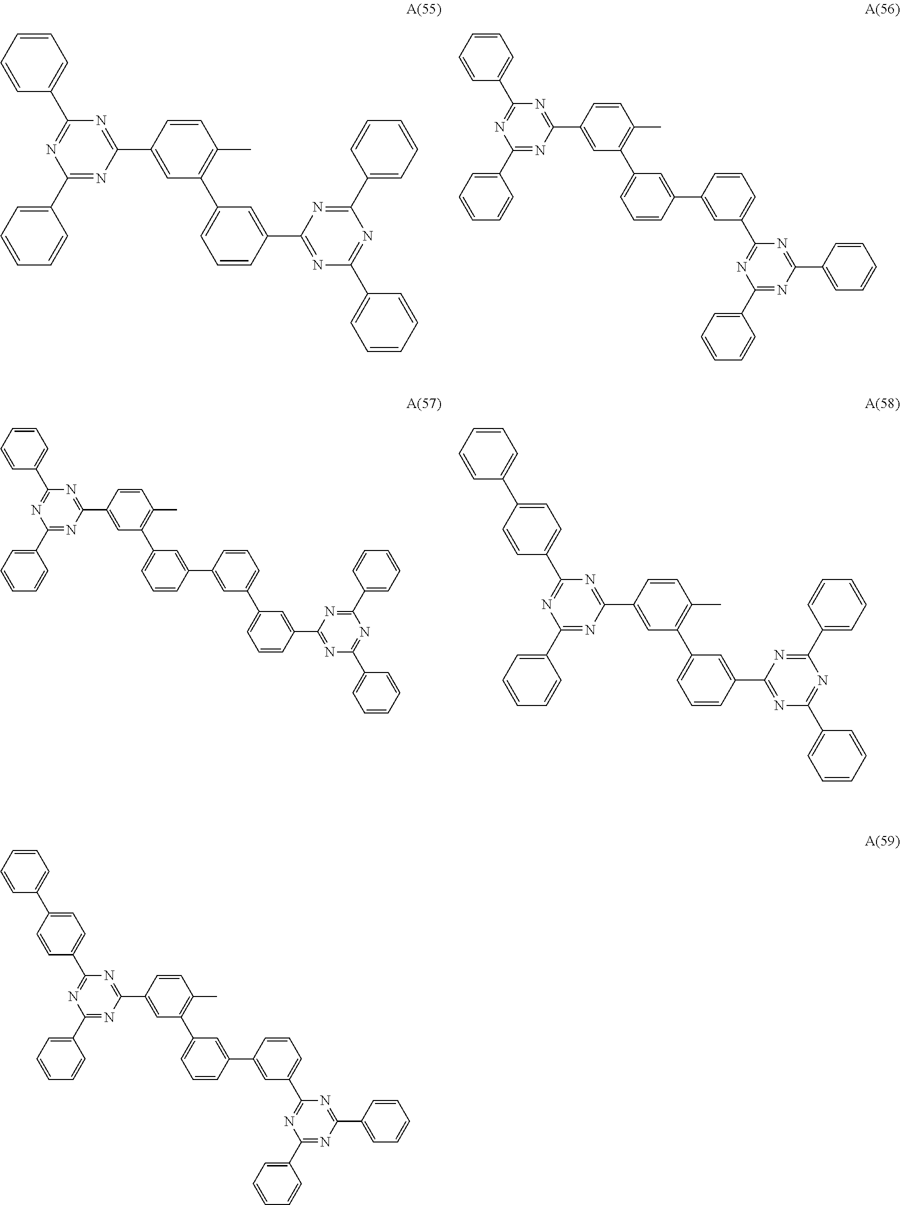 [SMILES: Cc1ccc(-c2nc(-c3ccccc3)nc(-c3ccccc3)n2)cc1-c1cccc(-c2nc(-c3ccccc3)nc(-c3ccccc3)n2)c1 ; Cc1ccc(-c2nc(-c3ccccc3)nc(-c3ccccc3)n2)cc1-c1cccc(-c2cccc(-c3nc(-c4ccccc4)nc(-c4ccccc4)n3)c2)c1 ; Cc1ccc(-c2nc(-c3ccccc3)nc(-c3ccccc3)n2)cc1-c1cccc(-c2cccc(-c3cccc(-c4nc(-c5ccccc5)nc(-c5ccccc5)n4)c3)c2)c1 ; Cc1ccc(-c2nc(-c3ccccc3)nc(-c3ccc(-c4ccccc4)cc3)n2)cc1-c1cccc(-c2nc(-c3ccccc3)nc(-c3ccccc3)n2)c1 ; Cc1ccc(-c2nc(-c3ccccc3)nc(-c3ccc(-c4ccccc4)cc3)n2)cc1-c1cccc(-c2cccc(-c3nc(-c4ccccc4)nc(-c4ccccc4)n3)c2)c1]

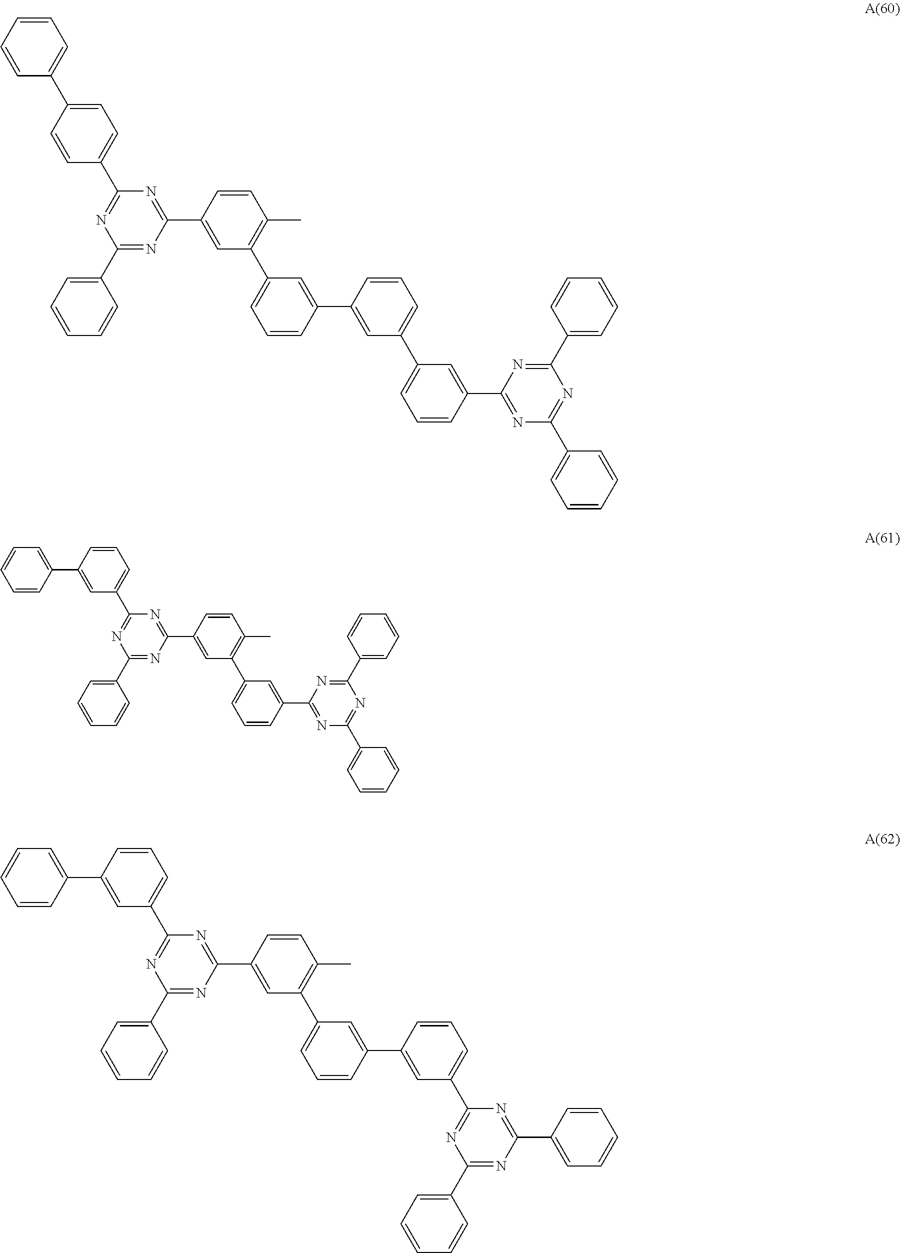 [SMILES: Cc1ccc(-c2nc(-c3ccccc3)nc(-c3ccc(-c4ccccc4)cc3)n2)cc1-c1cccc(-c2cccc(-c3cccc(-c4nc(-c5ccccc5)nc(-c5ccccc5)n4)c3)c2)c1 ; Cc1ccc(-c2nc(-c3ccccc3)nc(-c3cccc(-c4ccccc4)c3)n2)cc1-c1cccc(-c2nc(-c3ccccc3)nc(-c3ccccc3)n2)c1 ; Cc1ccc(-c2nc(-c3ccccc3)nc(-c3cccc(-c4ccccc4)c3)n2)cc1-c1cccc(-c2cccc(-c3nc(-c4ccccc4)nc(-c4ccccc4)n3)c2)c1]

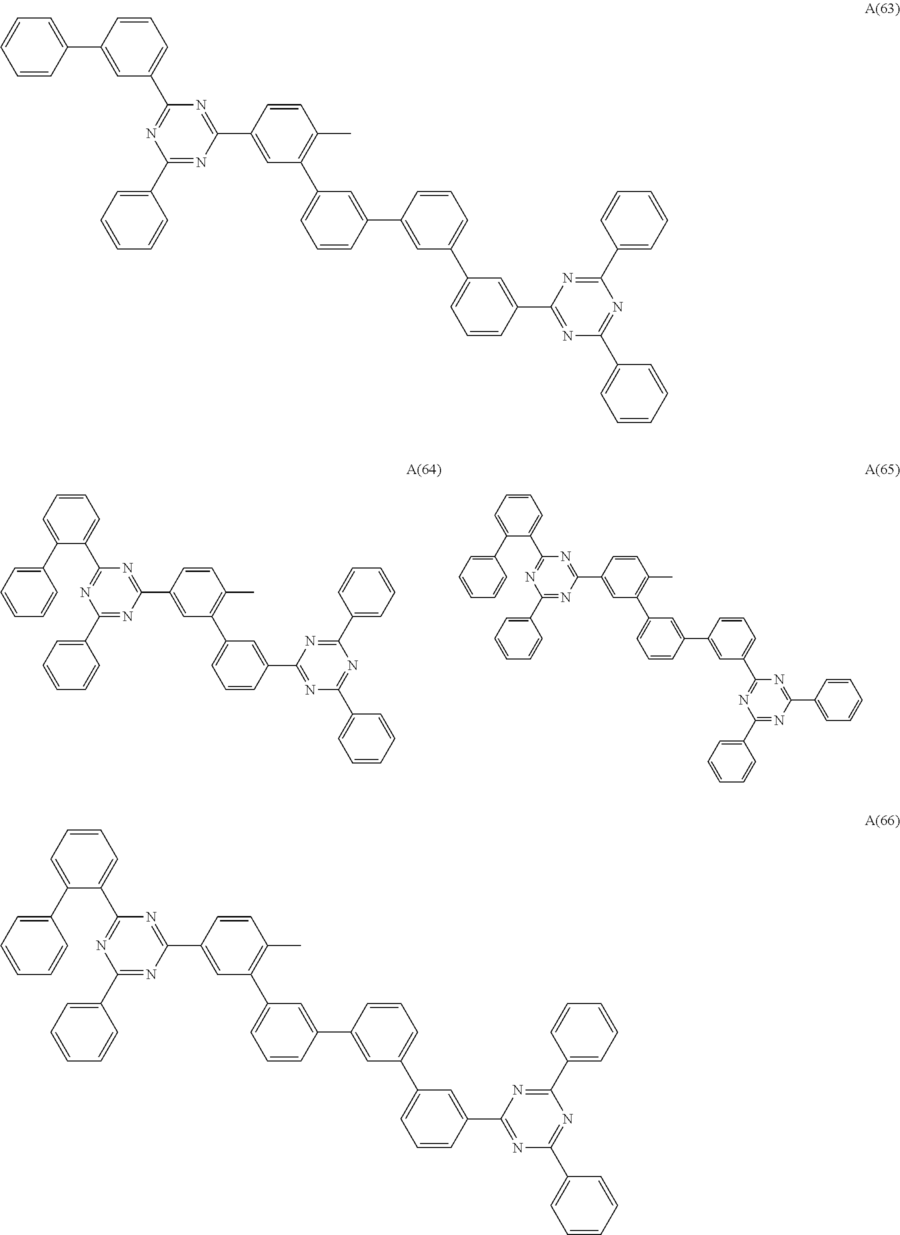 [SMILES: Cc1ccc(-c2nc(-c3ccccc3)nc(-c3cccc(-c4ccccc4)c3)n2)cc1-c1cccc(-c2cccc(-c3cccc(-c4nc(-c5ccccc5)nc(-c5ccccc5)n4)c3)c2)c1 ; Cc1ccc(-c2nc(-c3ccccc3)nc(-c3ccccc3-c3ccccc3)n2)cc1-c1cccc(-c2nc(-c3ccccc3)nc(-c3ccccc3)n2)c1 ; Cc1ccc(-c2nc(-c3ccccc3)nc(-c3ccccc3-c3ccccc3)n2)cc1-c1cccc(-c2cccc(-c3nc(-c4ccccc4)nc(-c4ccccc4)n3)c2)c1 ; Cc1ccc(-c2nc(-c3ccccc3)nc(-c3ccccc3-c3ccccc3)n2)cc1-c1cccc(-c2cccc(-c3cccc(-c4nc(-c5ccccc5)nc(-c5ccccc5)n4)c3)c2)c1]

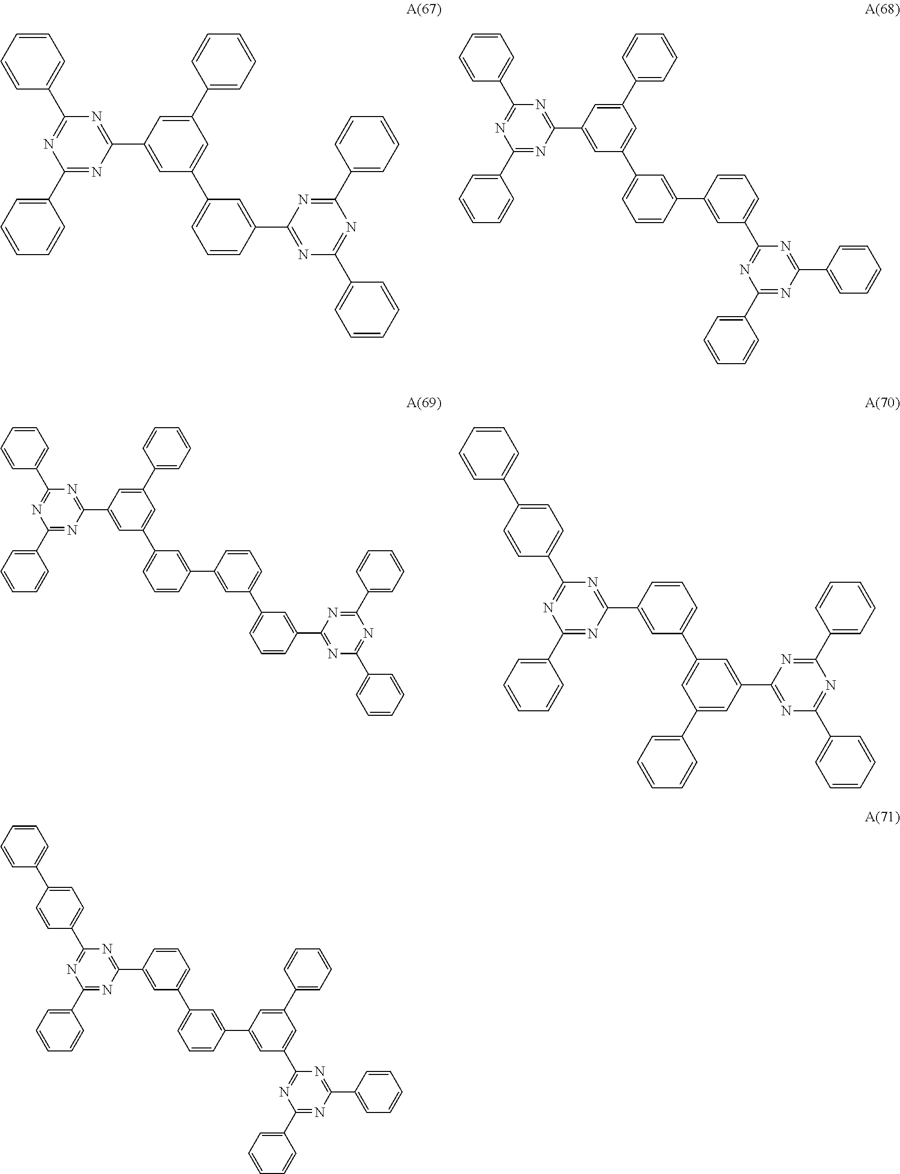

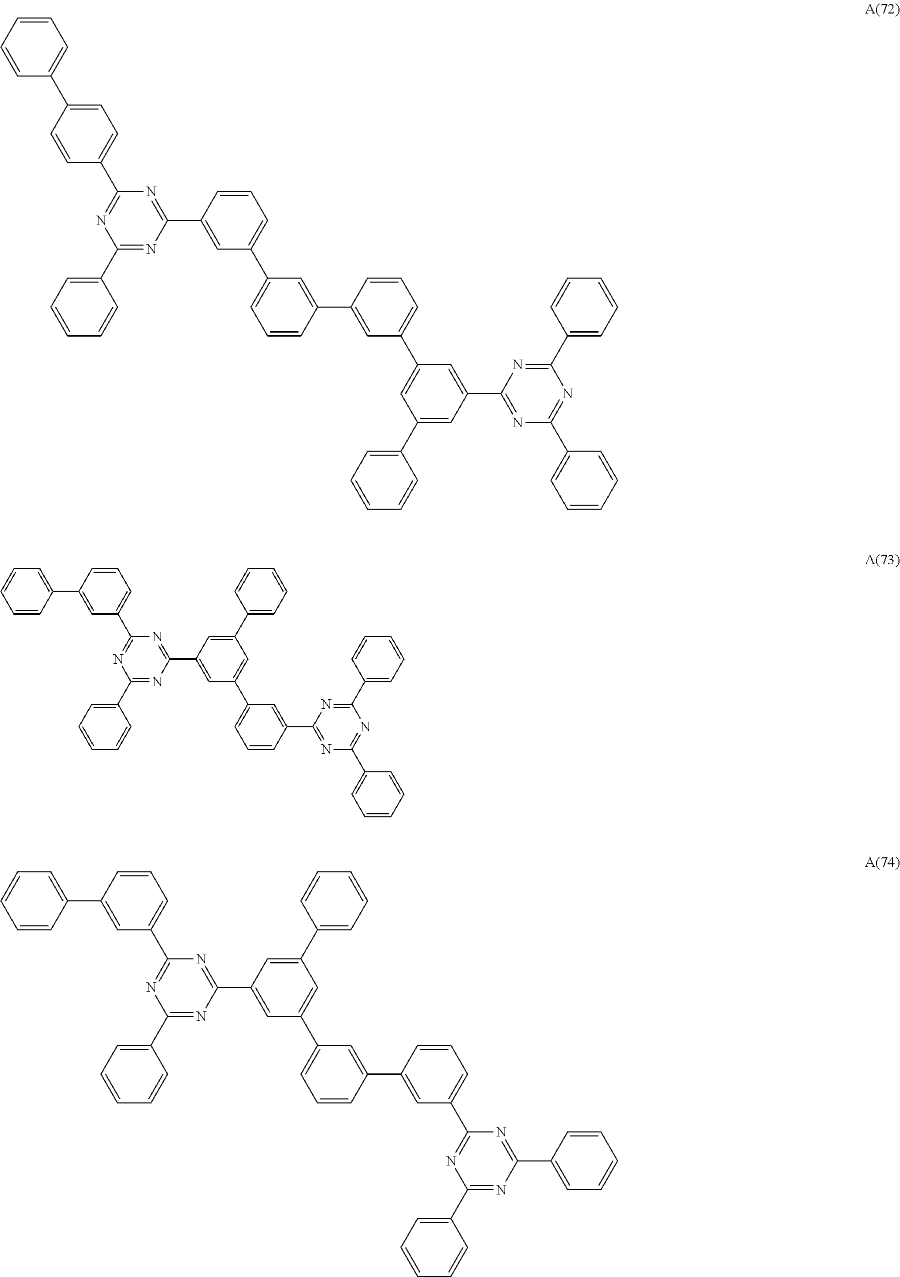 [SMILES: c1ccc(-c2ccc(-c3nc(-c4ccccc4)nc(-c4cccc(-c5cccc(-c6cccc(-c7cc(-c8ccccc8)cc(-c8nc(-c9ccccc9)nc(-c9ccccc9)n8)c7)c6)c5)c4)n3)cc2)cc1 ; c1ccc(-c2cccc(-c3nc(-c4ccccc4)nc(-c4cc(-c5ccccc5)cc(-c5cccc(-c6nc(-c7ccccc7)nc(-c7ccccc7)n6)c5)c4)n3)c2)cc1 ; c1ccc(-c2cccc(-c3nc(-c4ccccc4)nc(-c4cc(-c5ccccc5)cc(-c5cccc(-c6cccc(-c7nc(-c8ccccc8)nc(-c8ccccc8)n7)c6)c5)c4)n3)c2)cc1]

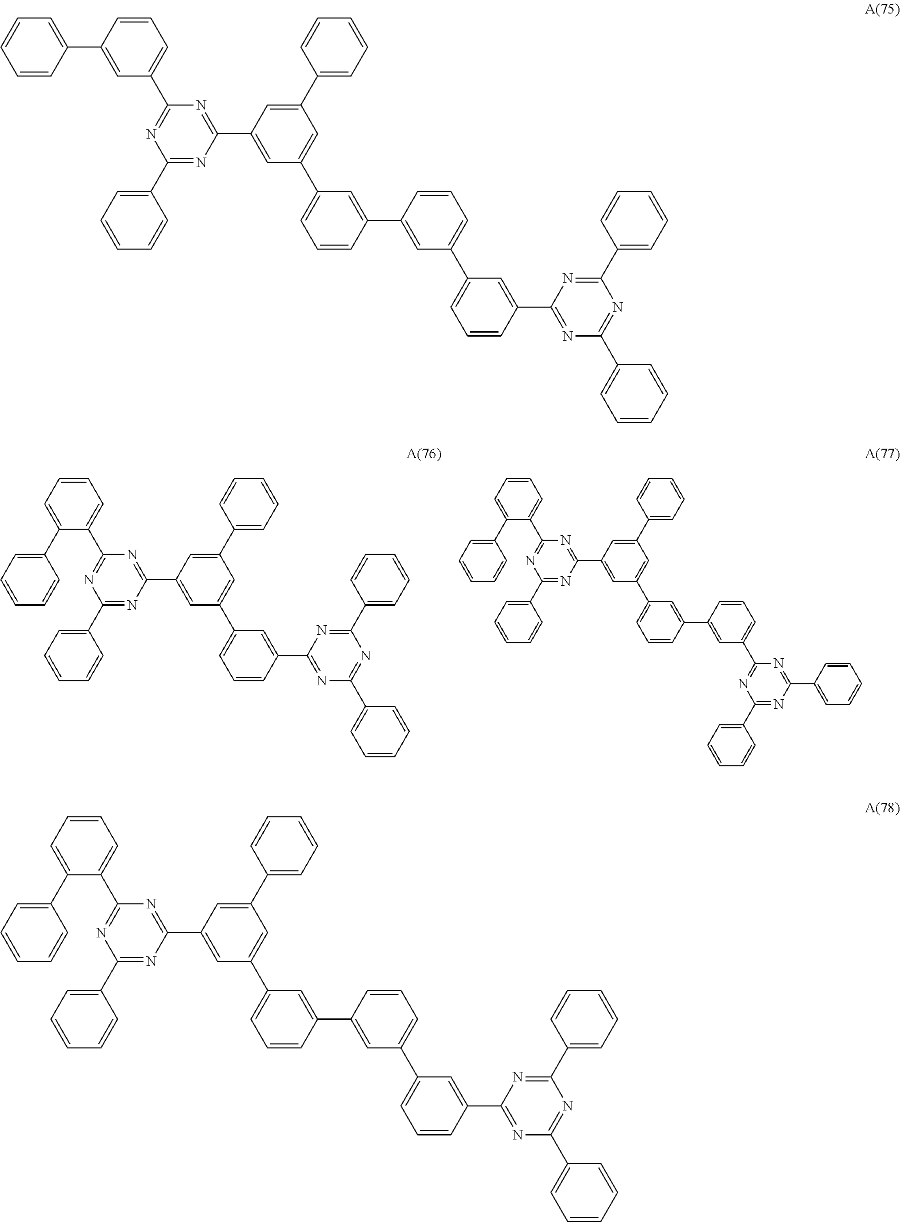 [SMILES: c1ccc(-c2cccc(-c3nc(-c4ccccc4)nc(-c4cc(-c5ccccc5)cc(-c5cccc(-c6cccc(-c7cccc(-c8nc(-c9ccccc9)nc(-c9ccccc9)n8)c7)c6)c5)c4)n3)c2)cc1 ; c1ccc(-c2cc(-c3cccc(-c4nc(-c5ccccc5)nc(-c5ccccc5)n4)c3)cc(-c3nc(-c4ccccc4)nc(-c4ccccc4-c4ccccc4)n3)c2)cc1 ; c1ccc(-c2cc(-c3cccc(-c4cccc(-c5nc(-c6ccccc6)nc(-c6ccccc6)n5)c4)c3)cc(-c3nc(-c4ccccc4)nc(-c4ccccc4-c4ccccc4)n3)c2)cc1 ; c1ccc(-c2cc(-c3cccc(-c4cccc(-c5cccc(-c6nc(-c7ccccc7)nc(-c7ccccc7)n6)c5)c4)c3)cc(-c3nc(-c4ccccc4)nc(-c4ccccc4-c4ccccc4)n3)c2)cc1]

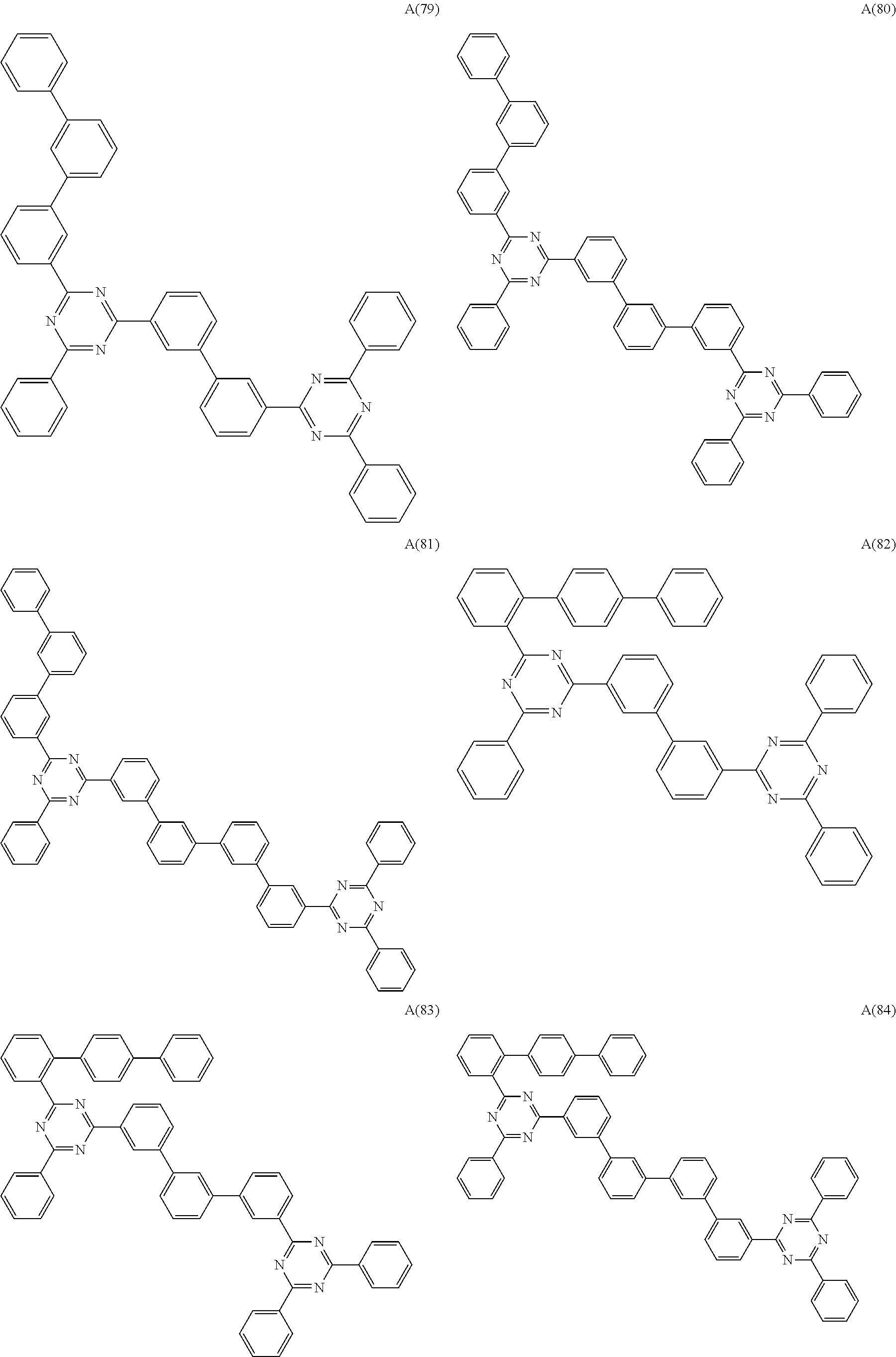

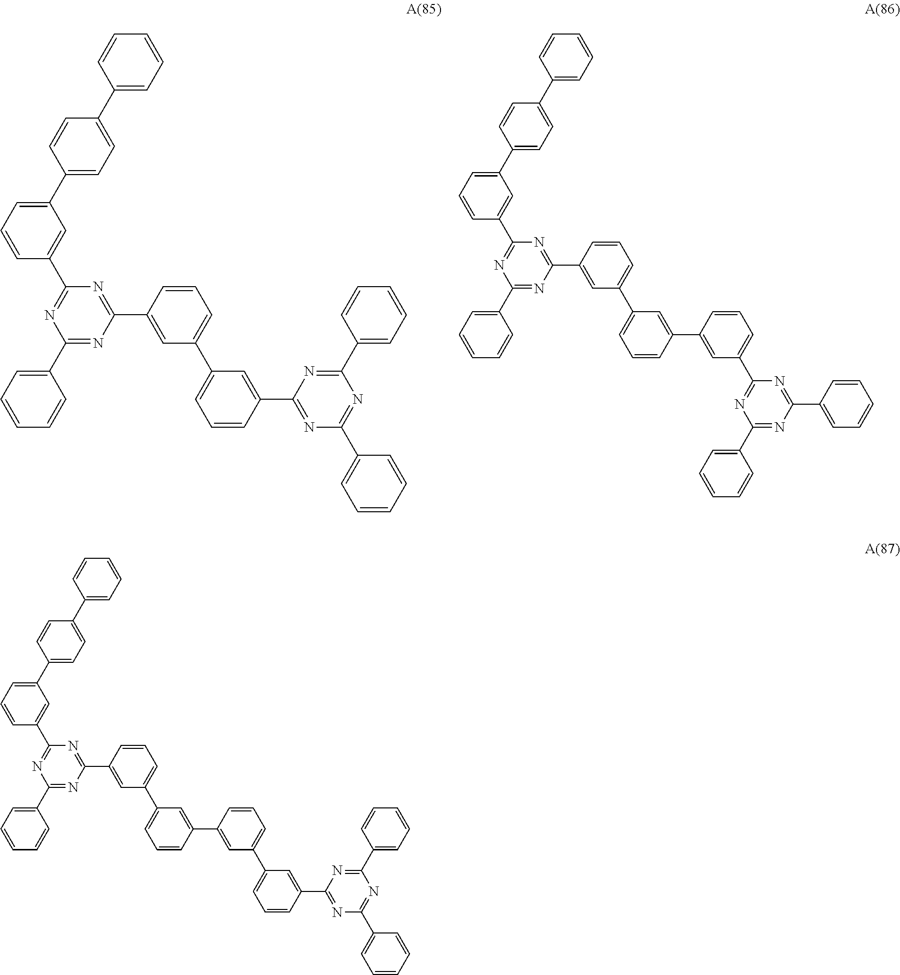 [SMILES: c1ccc(-c2ccc(-c3cccc(-c4nc(-c5ccccc5)nc(-c5cccc(-c6cccc(-c7nc(-c8ccccc8)nc(-c8ccccc8)n7)c6)c5)n4)c3)cc2)cc1 ; c1ccc(-c2ccc(-c3cccc(-c4nc(-c5ccccc5)nc(-c5cccc(-c6cccc(-c7cccc(-c8nc(-c9ccccc9)nc(-c9ccccc9)n8)c7)c6)c5)n4)c3)cc2)cc1 ; c1ccc(-c2ccc(-c3cccc(-c4nc(-c5ccccc5)nc(-c5cccc(-c6cccc(-c7cccc(-c8cccc(-c9nc(-c%10ccccc%10)nc(-c%10ccccc%10)n9)c8)c7)c6)c5)n4)c3)cc2)cc1]

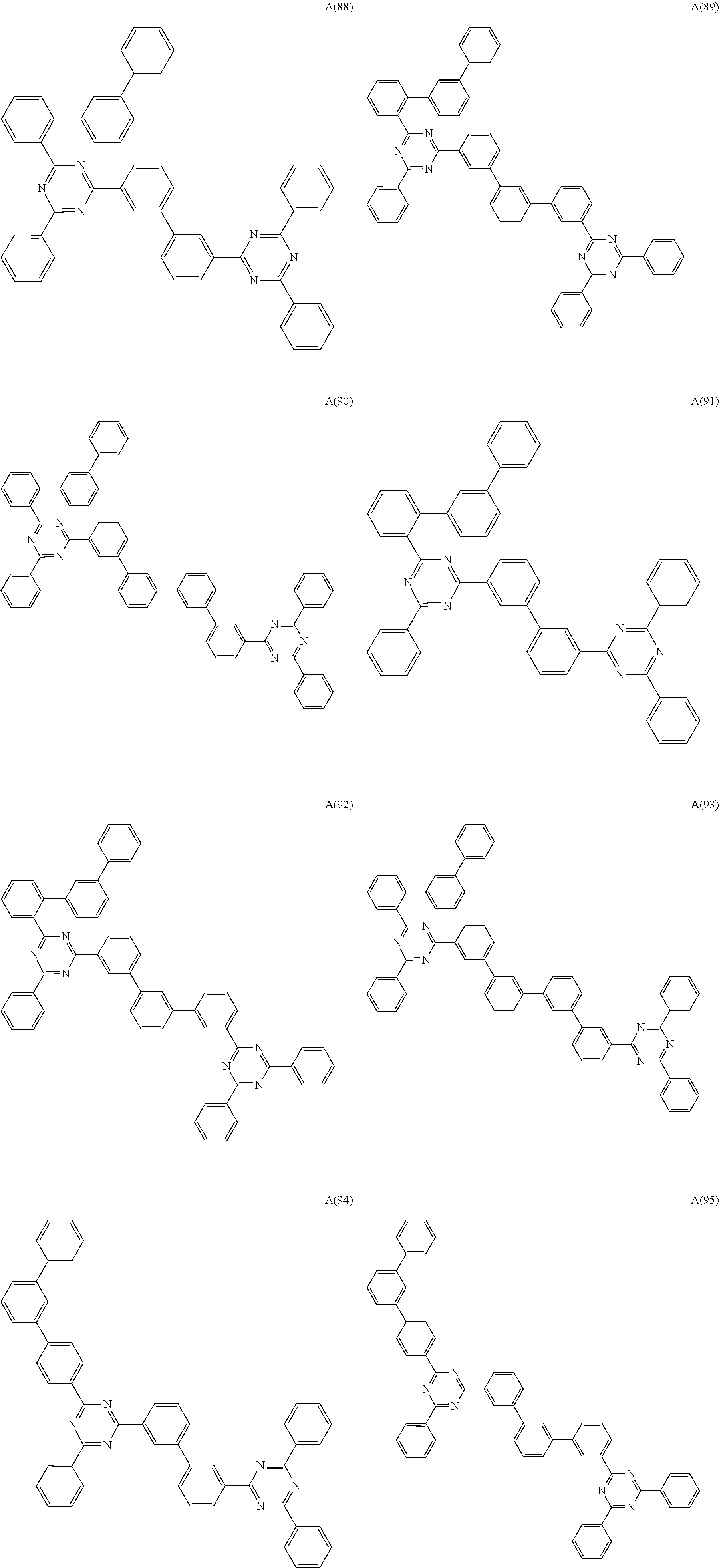

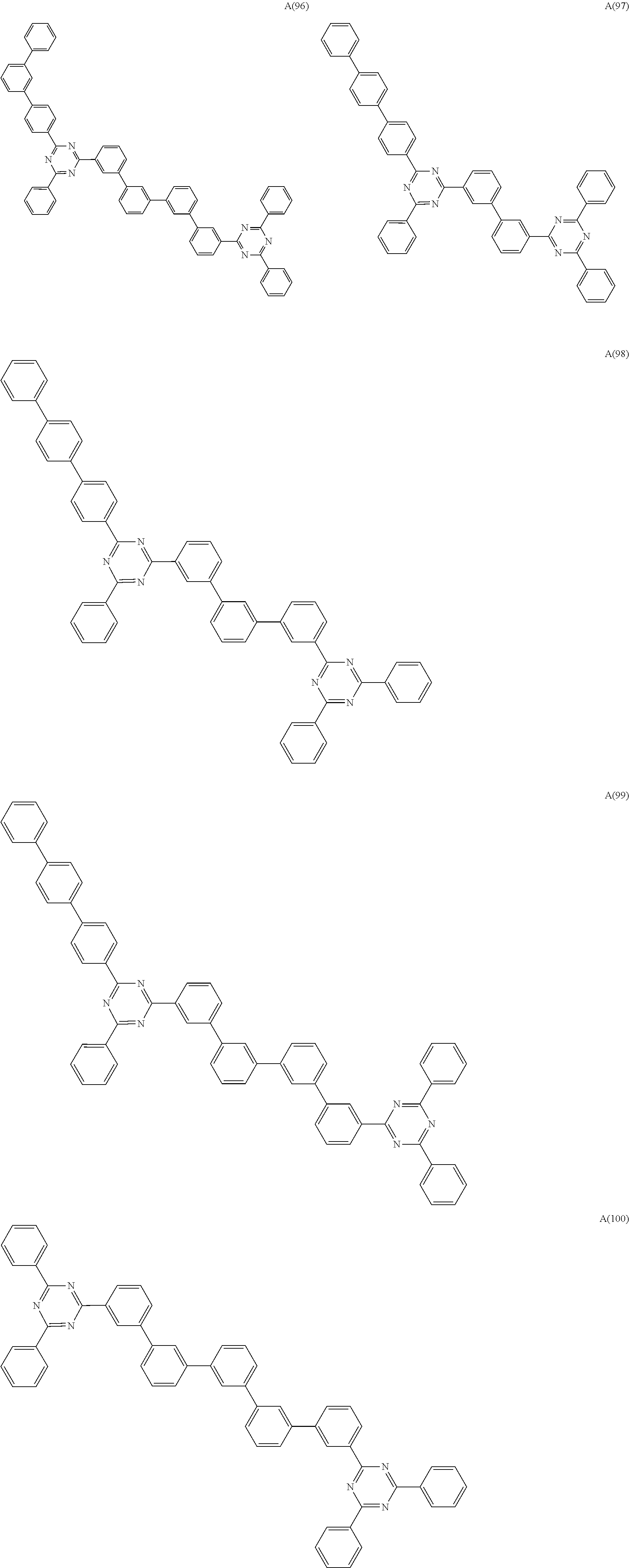

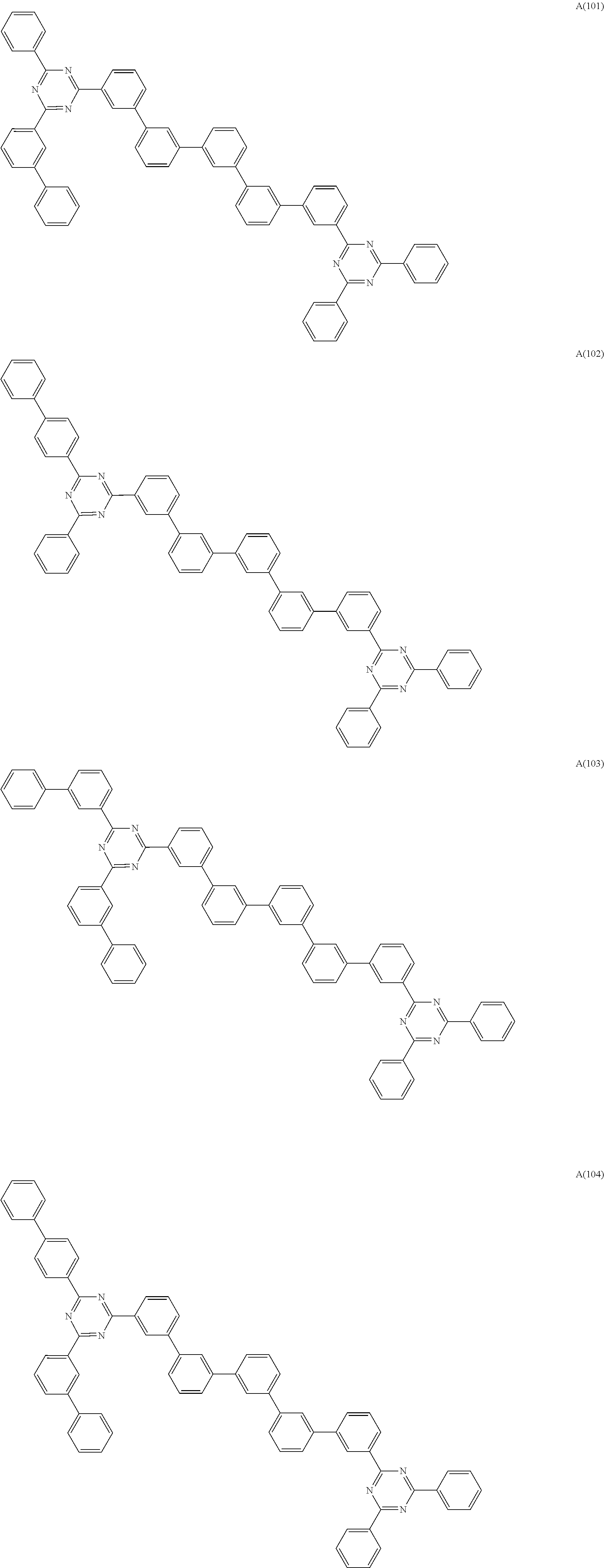

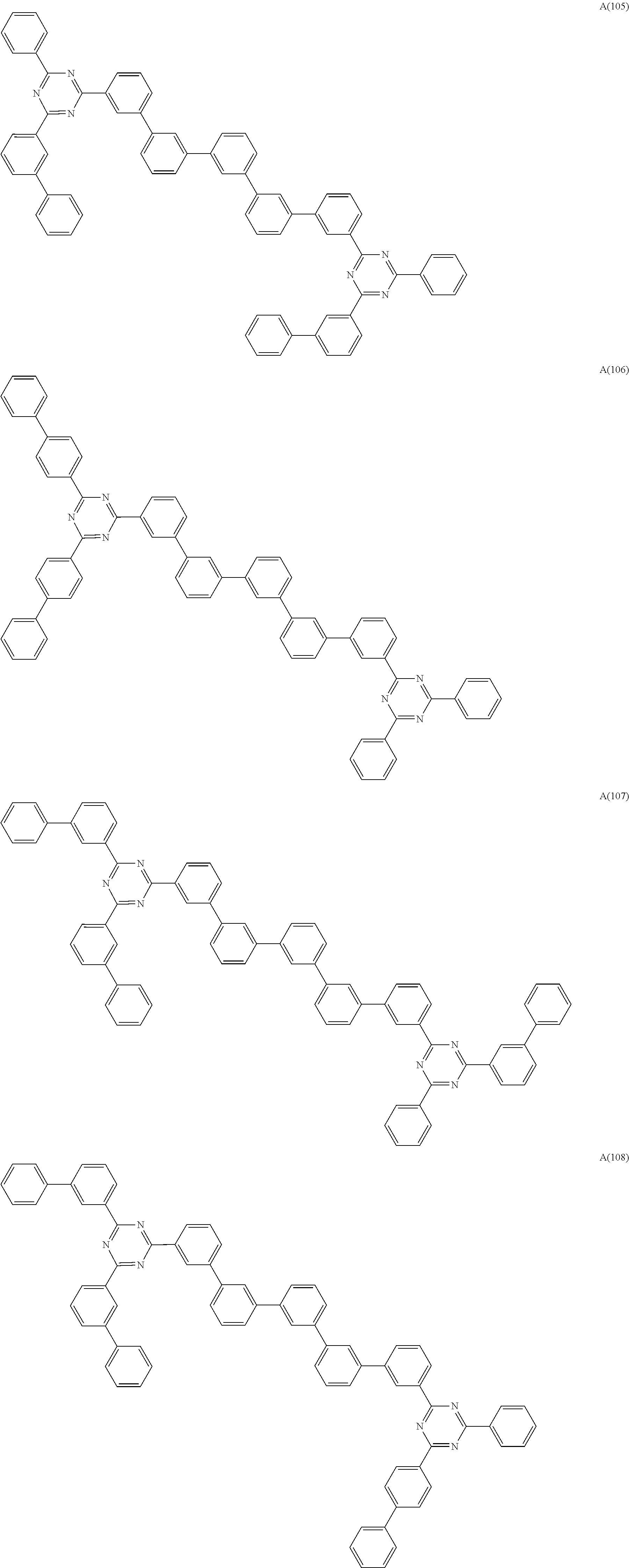

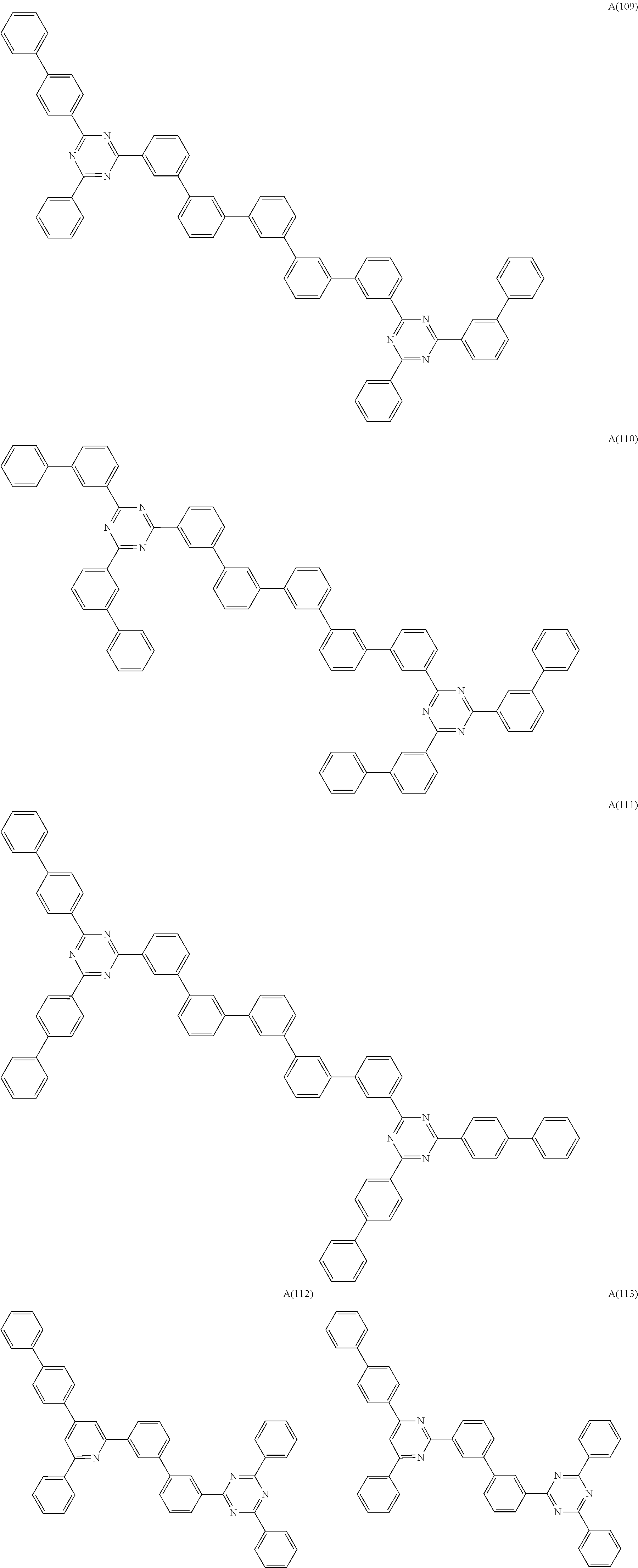

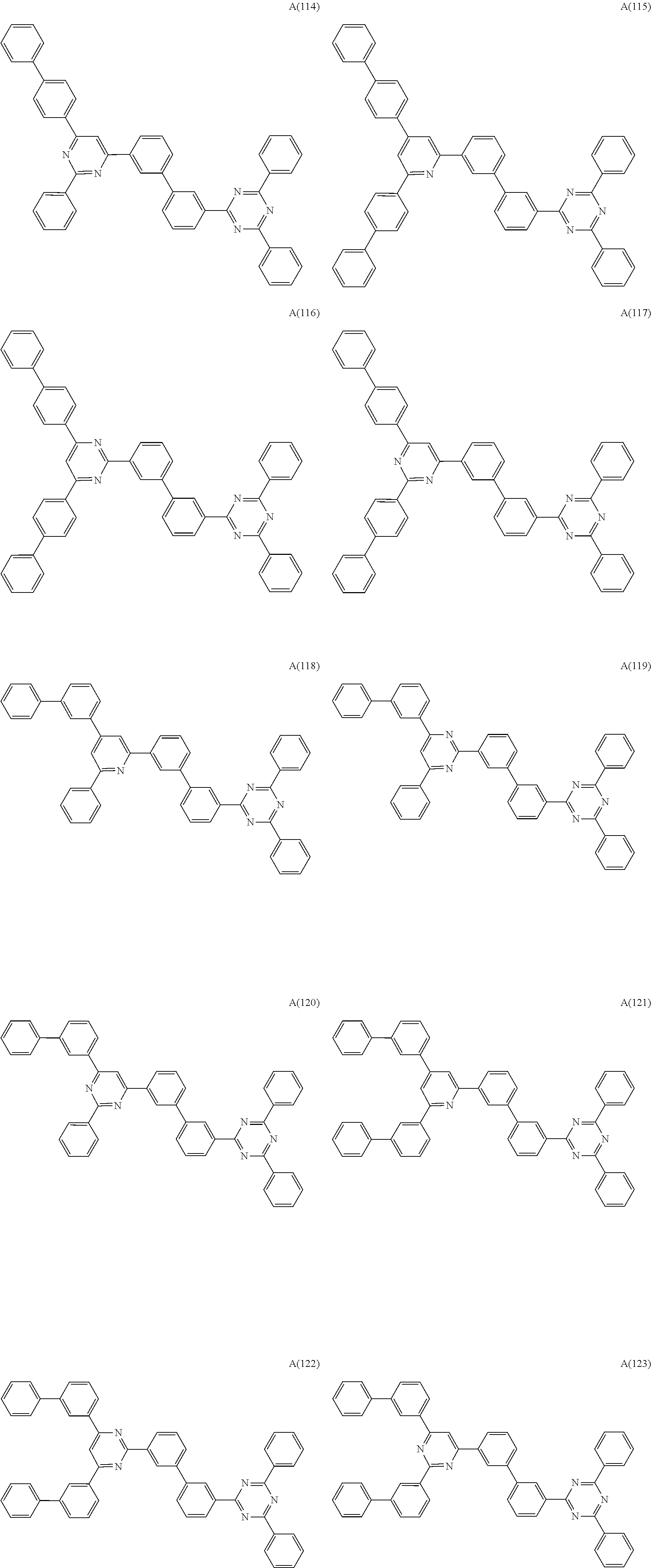

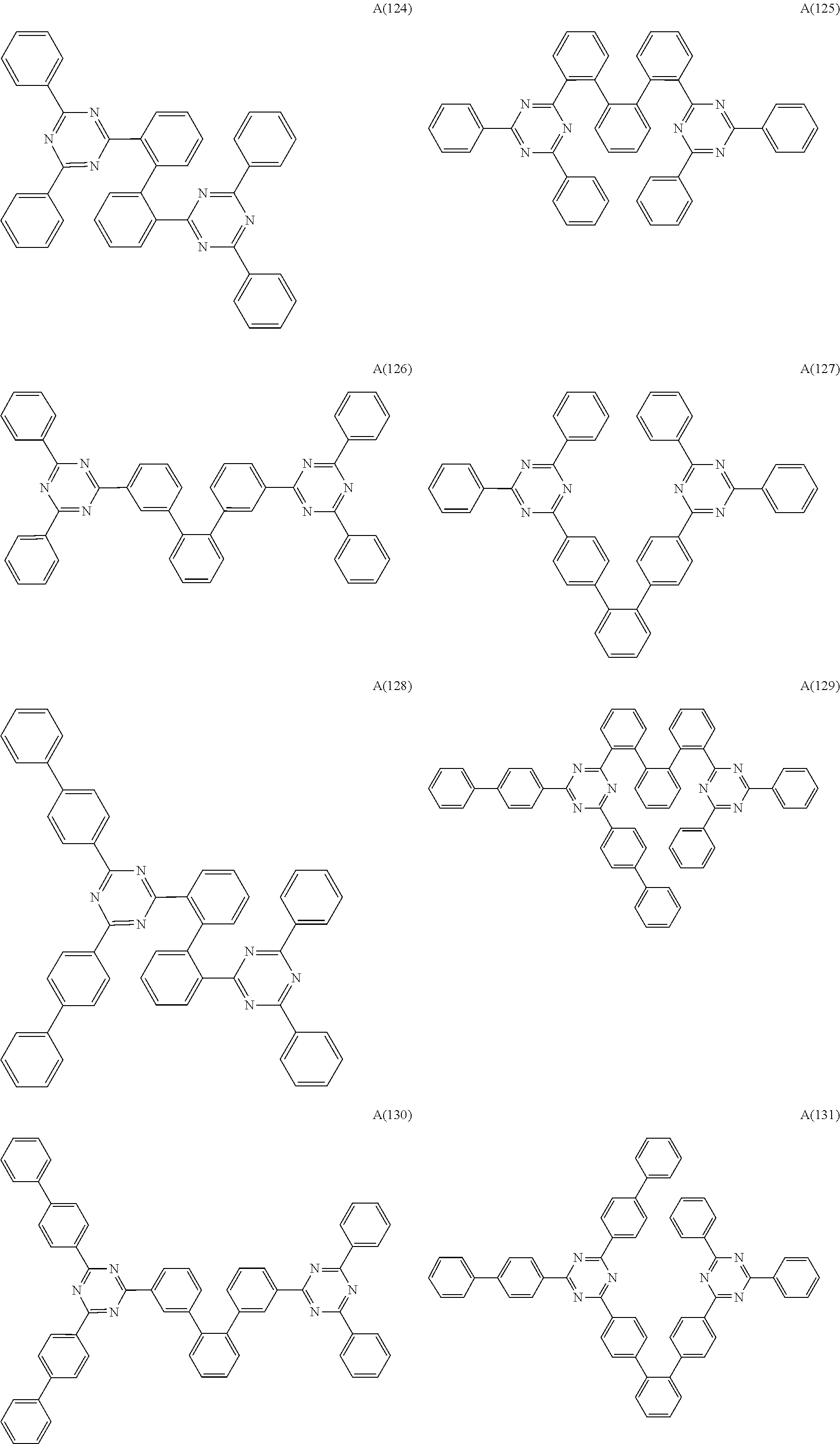

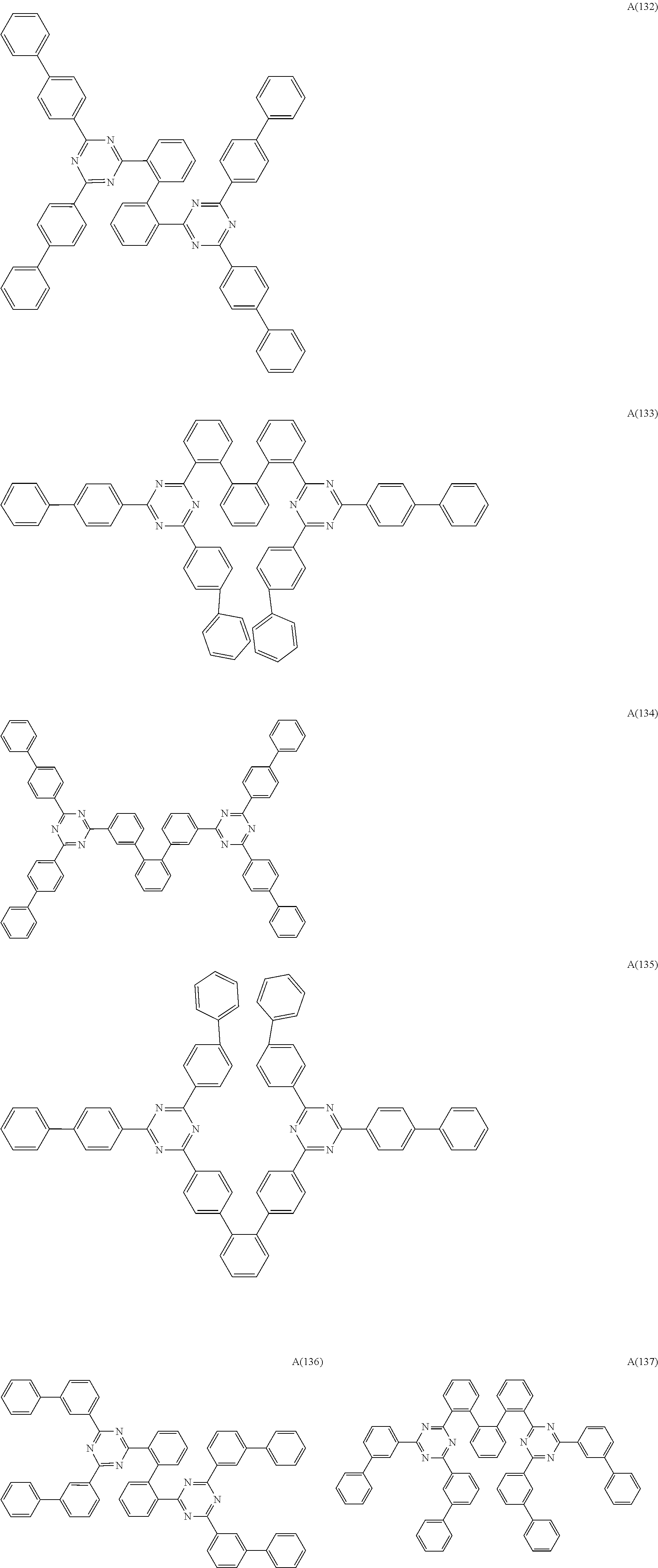

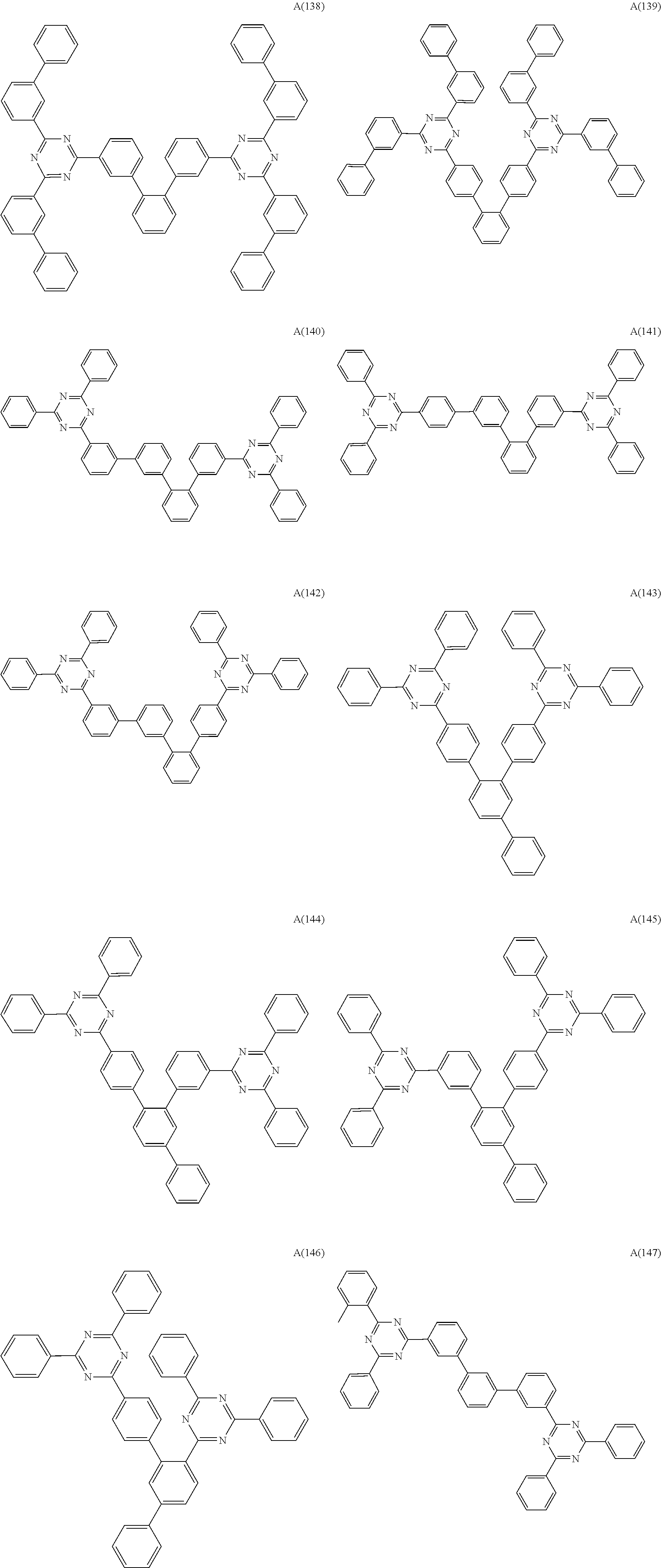

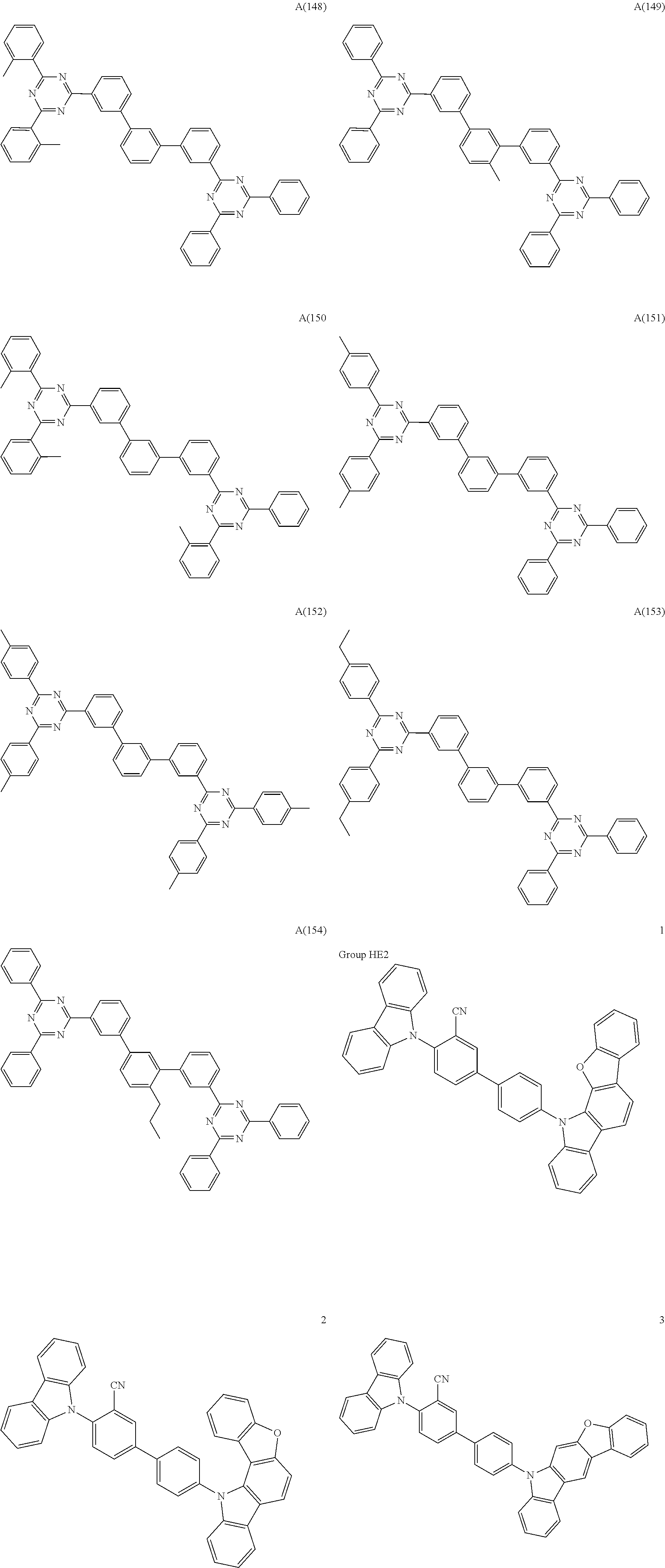

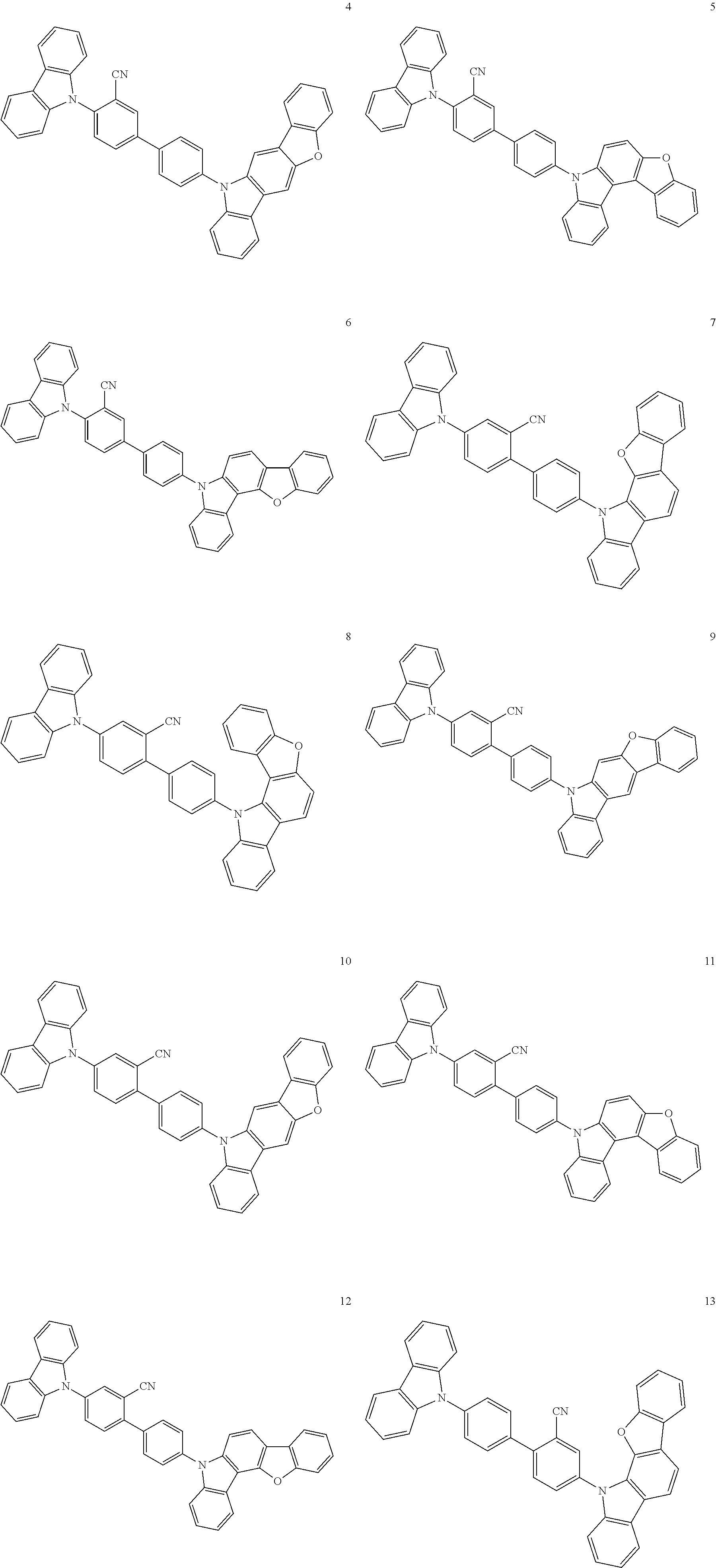

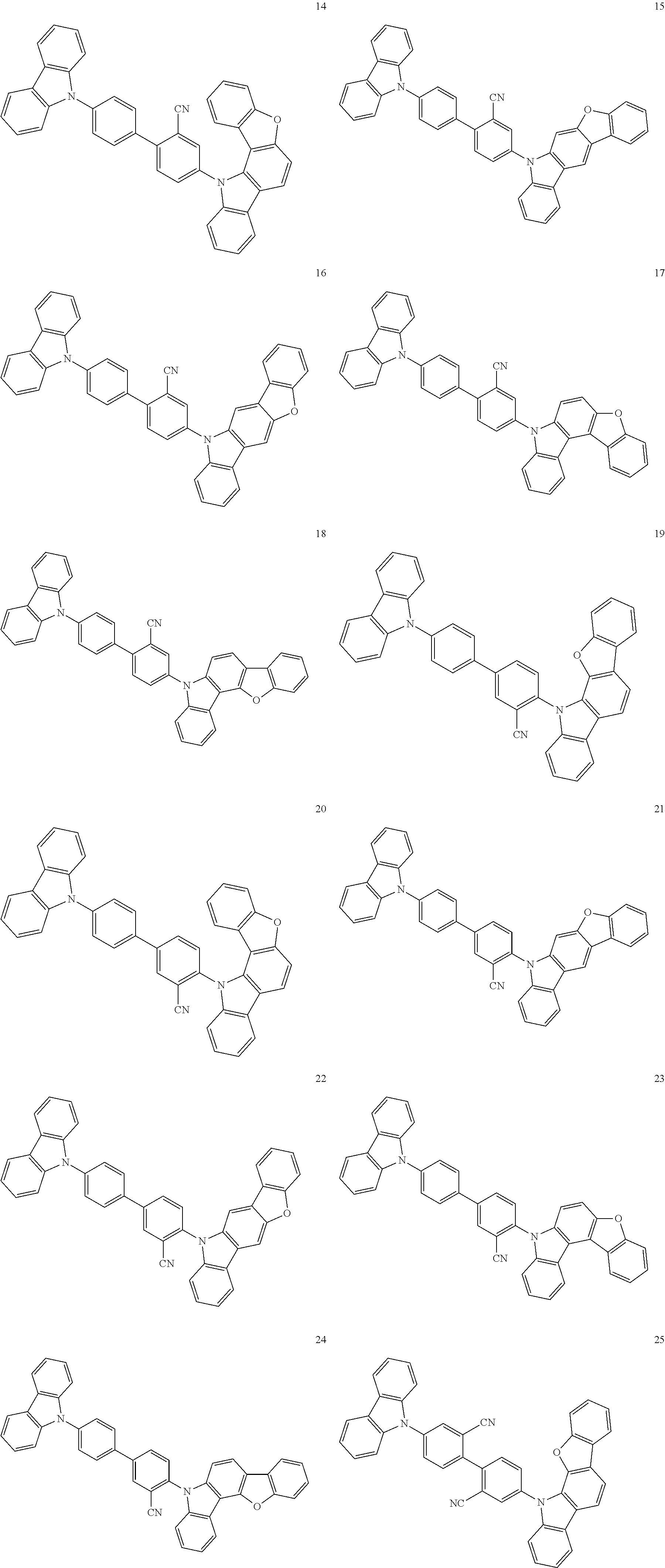

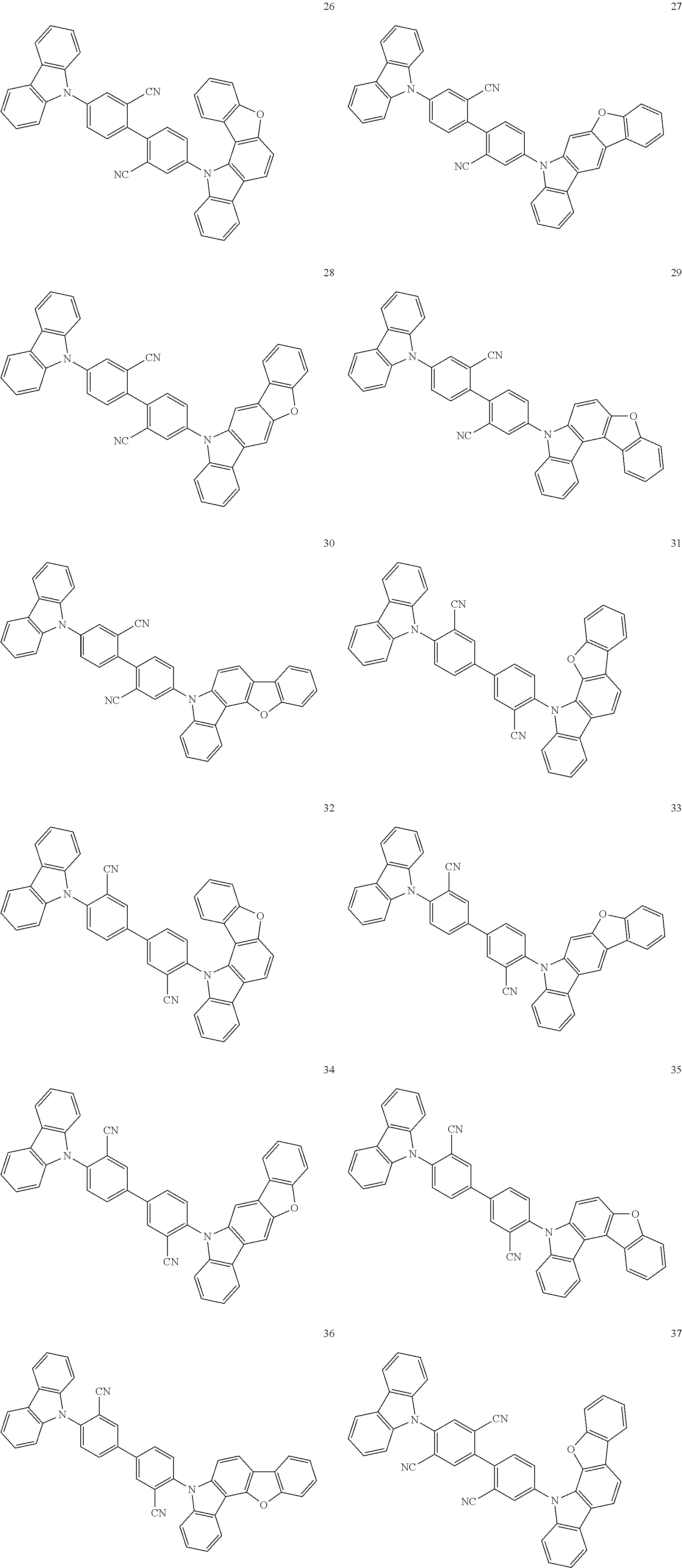

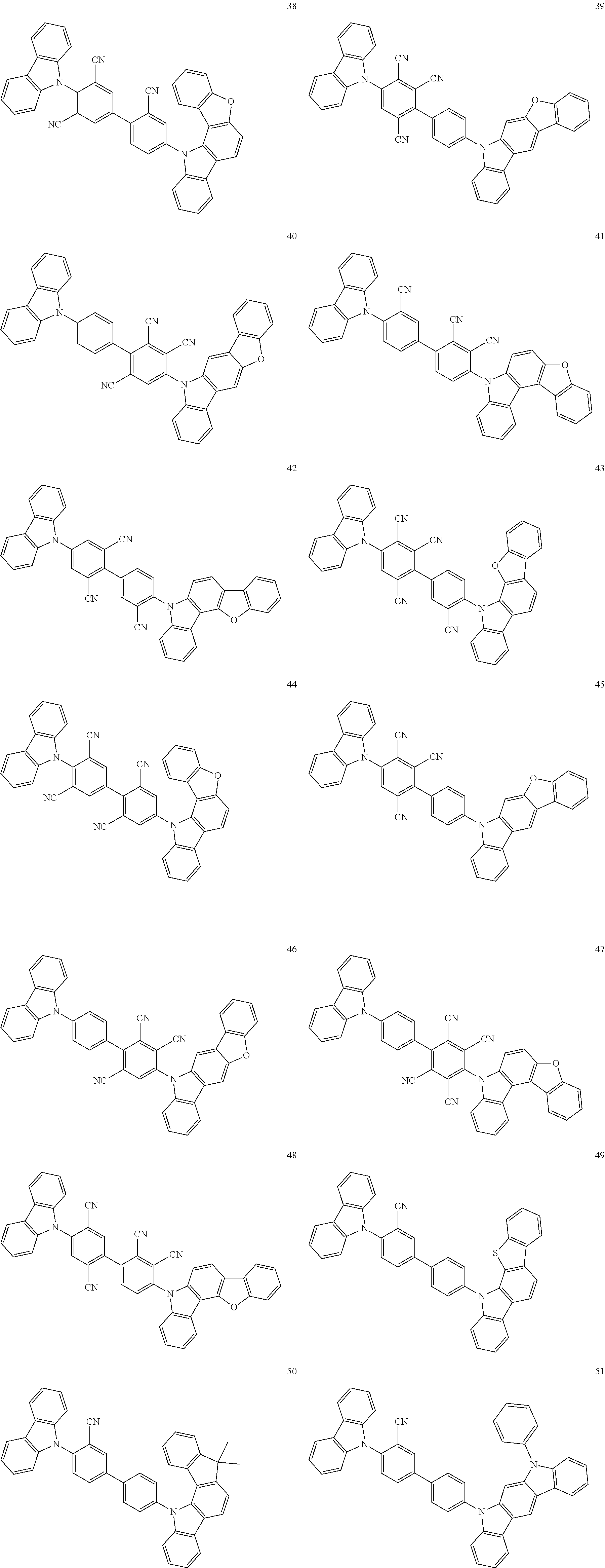

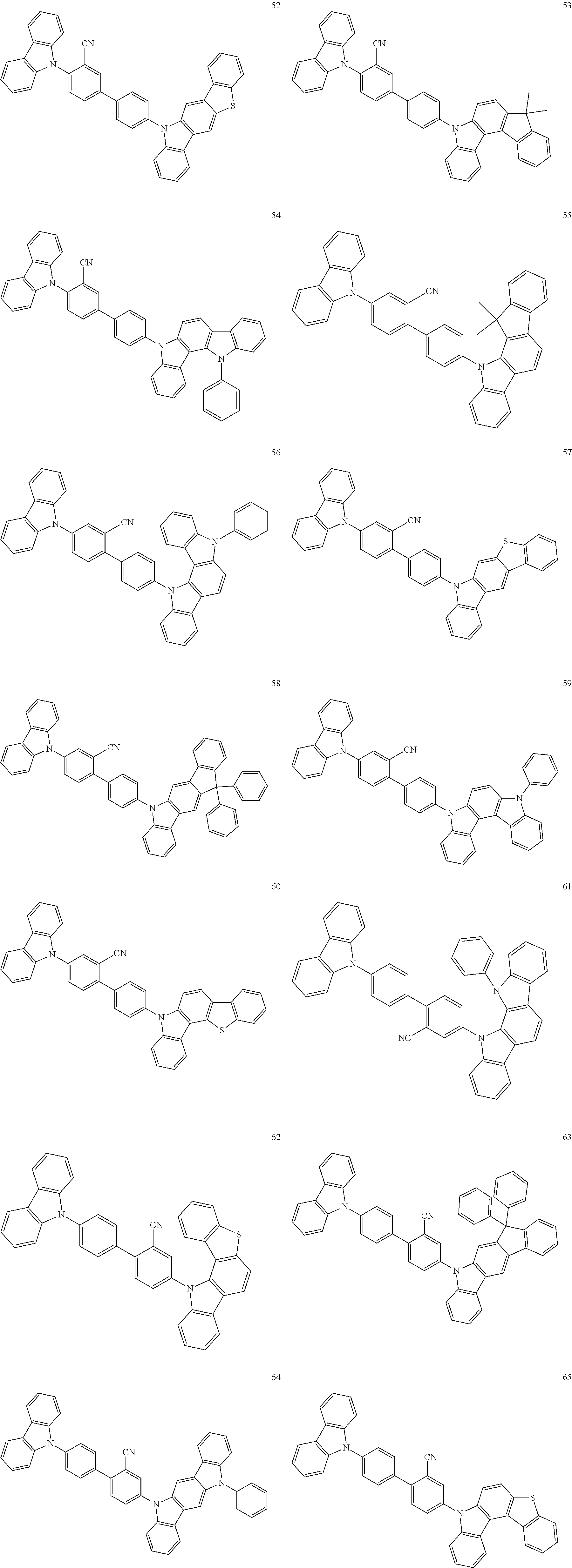

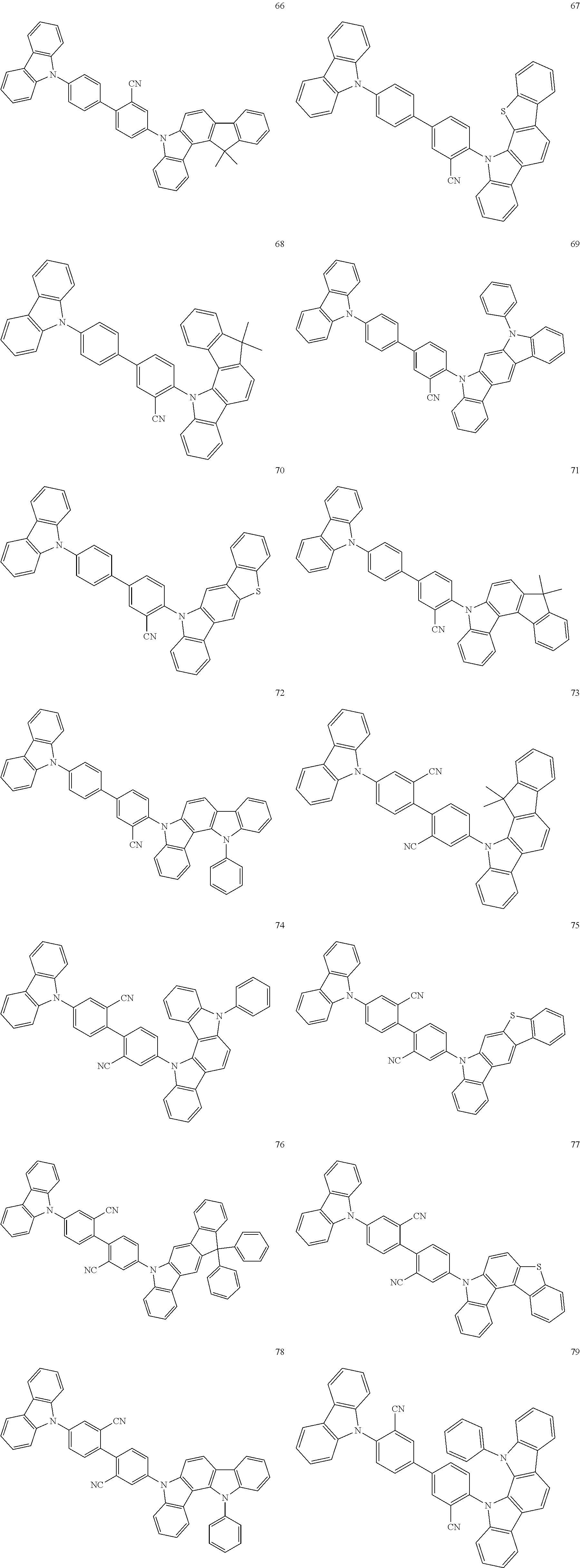

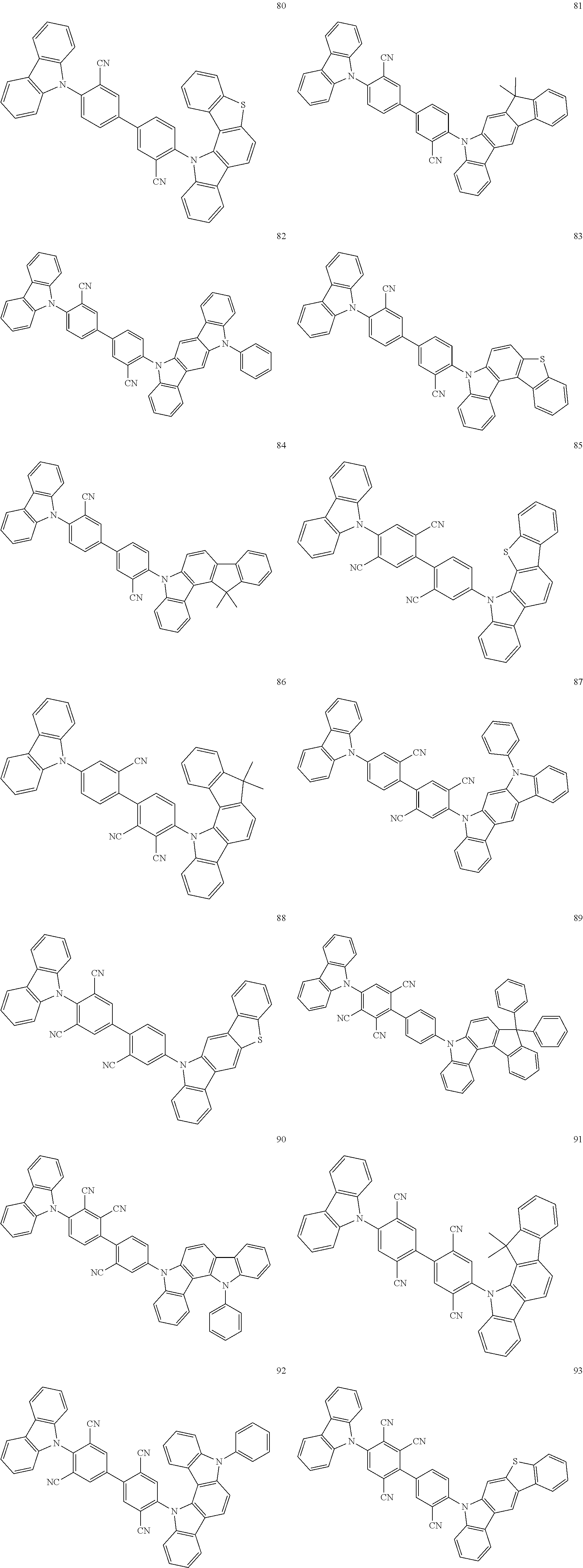

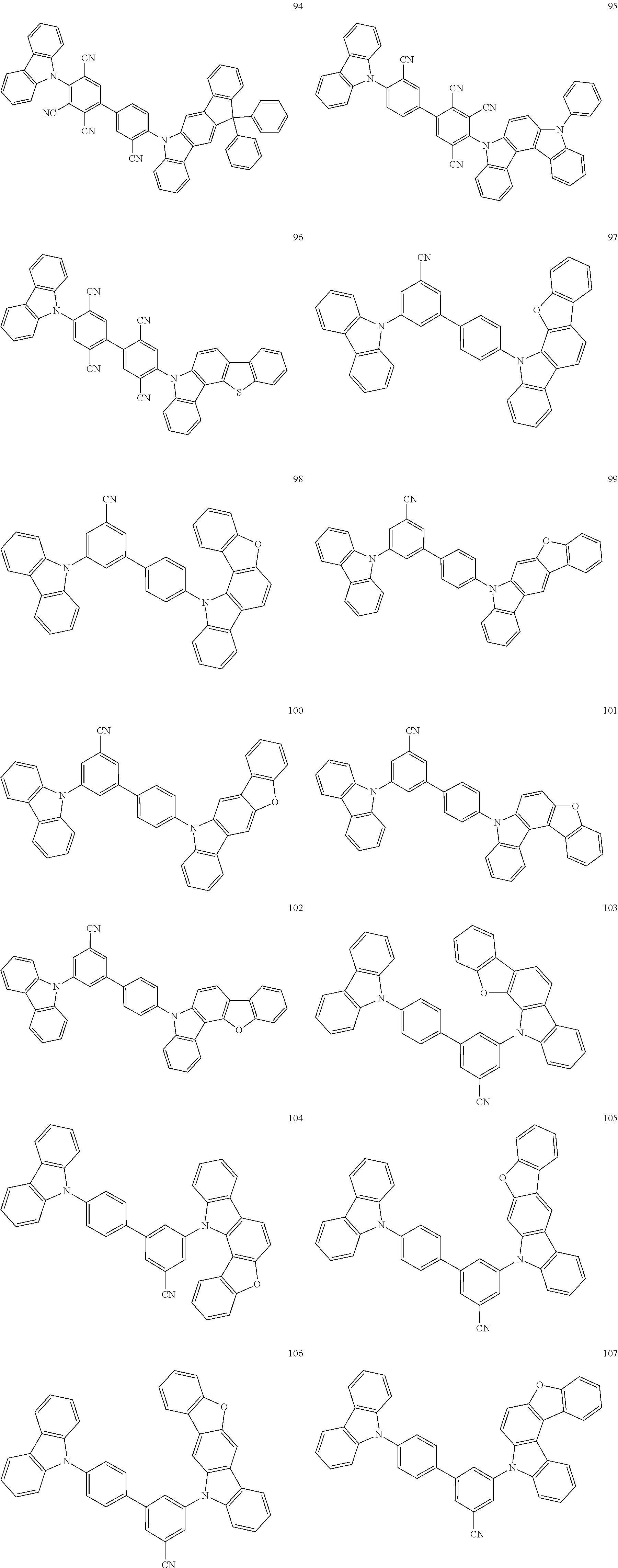

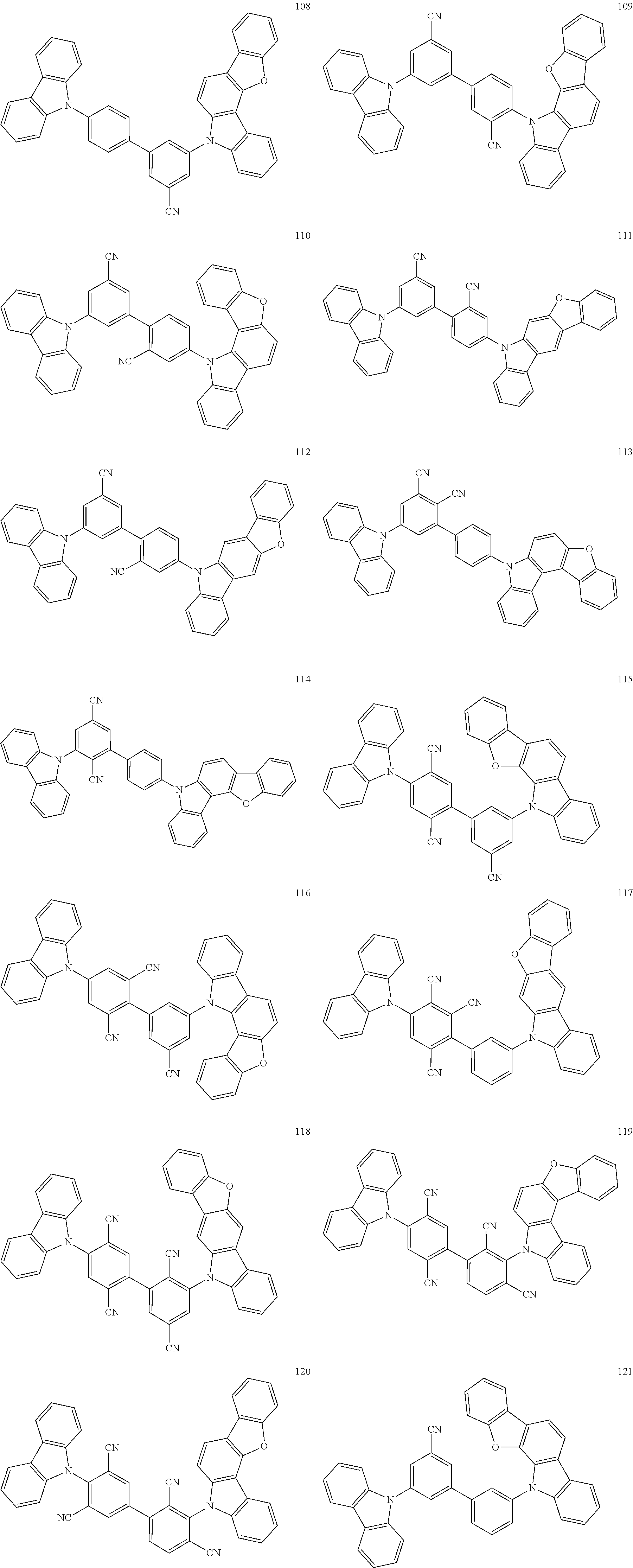

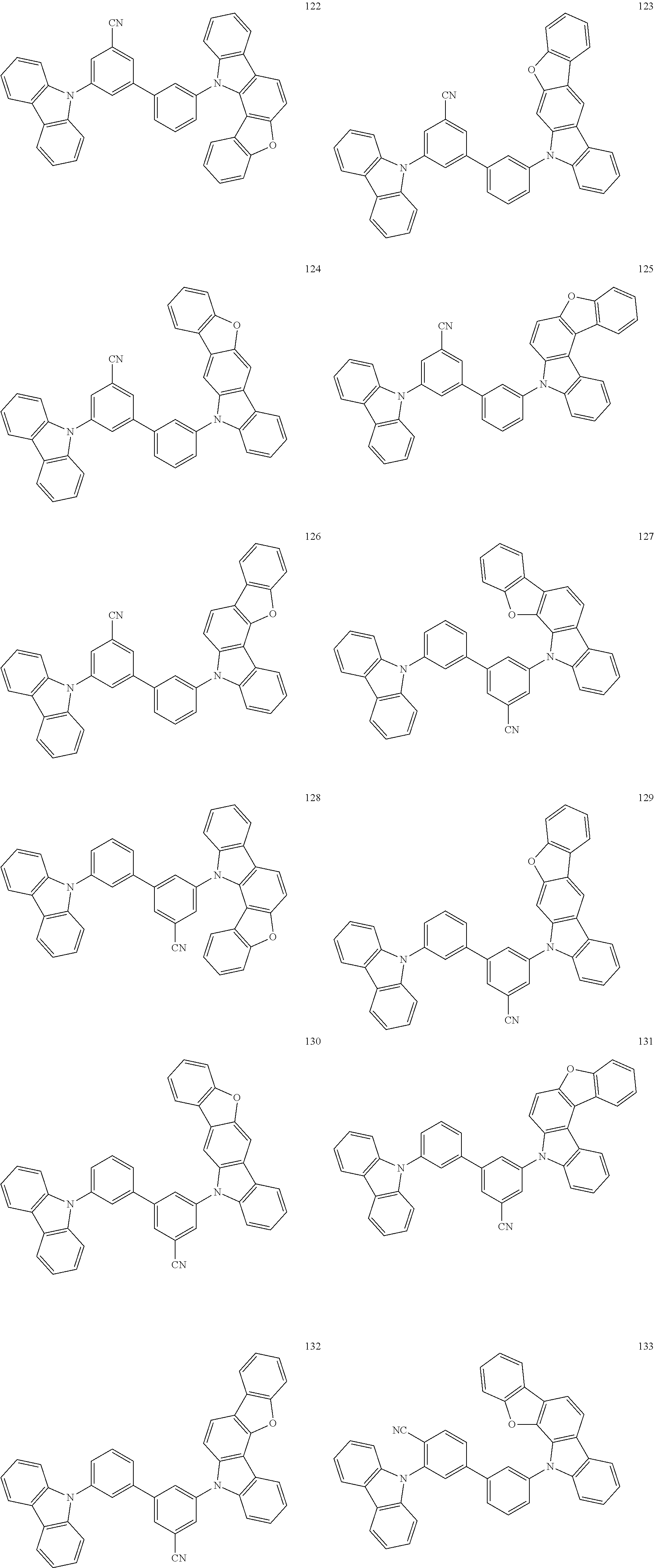

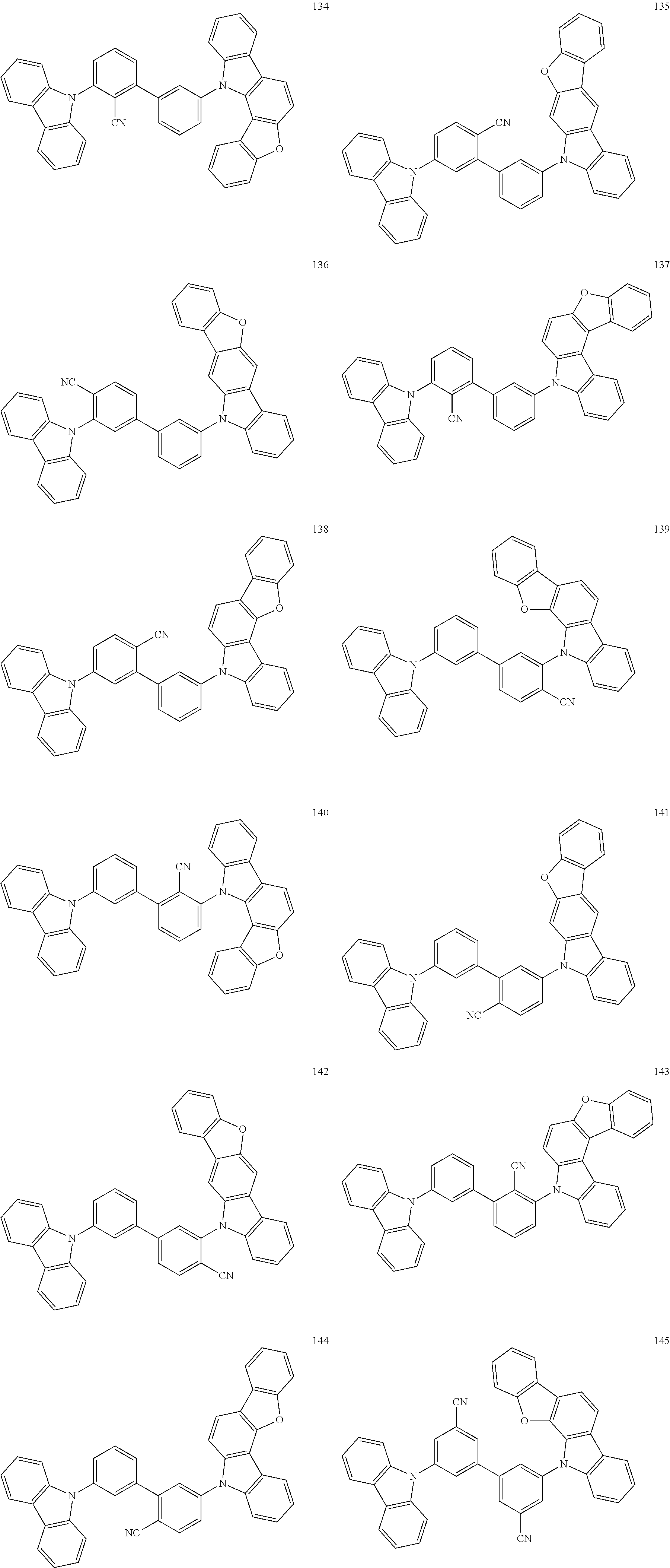

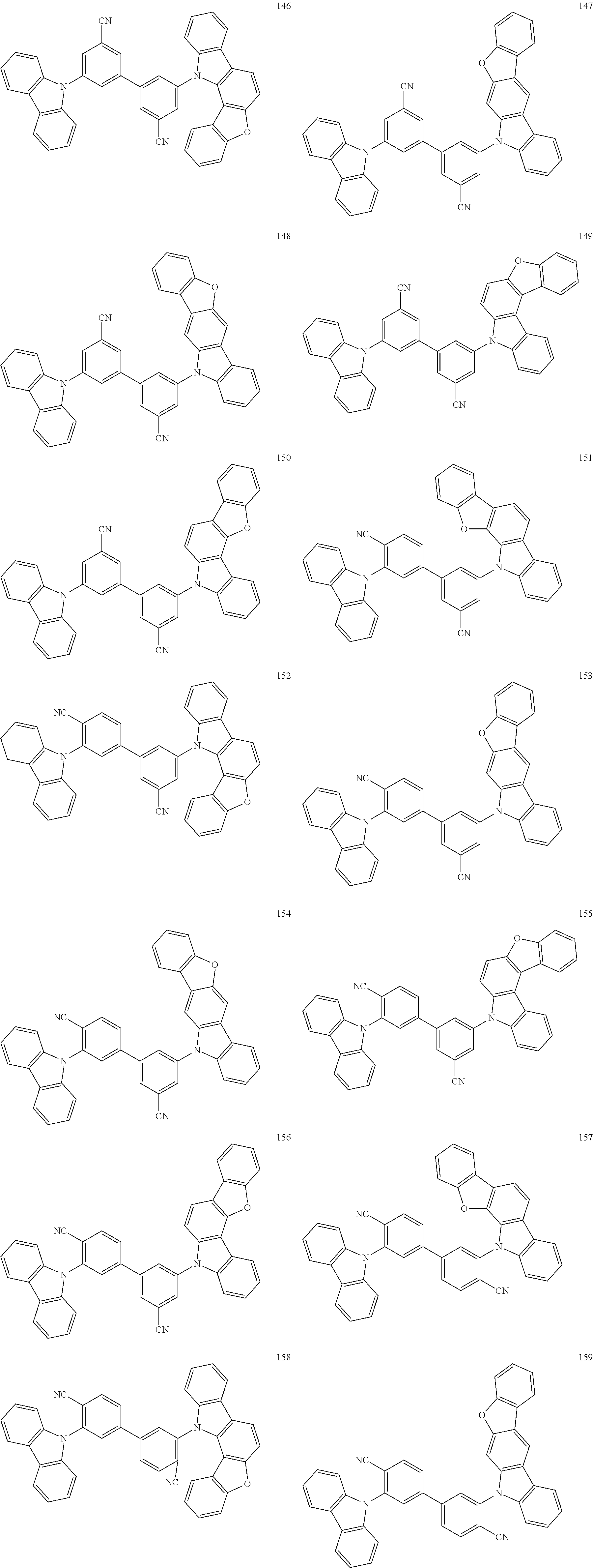

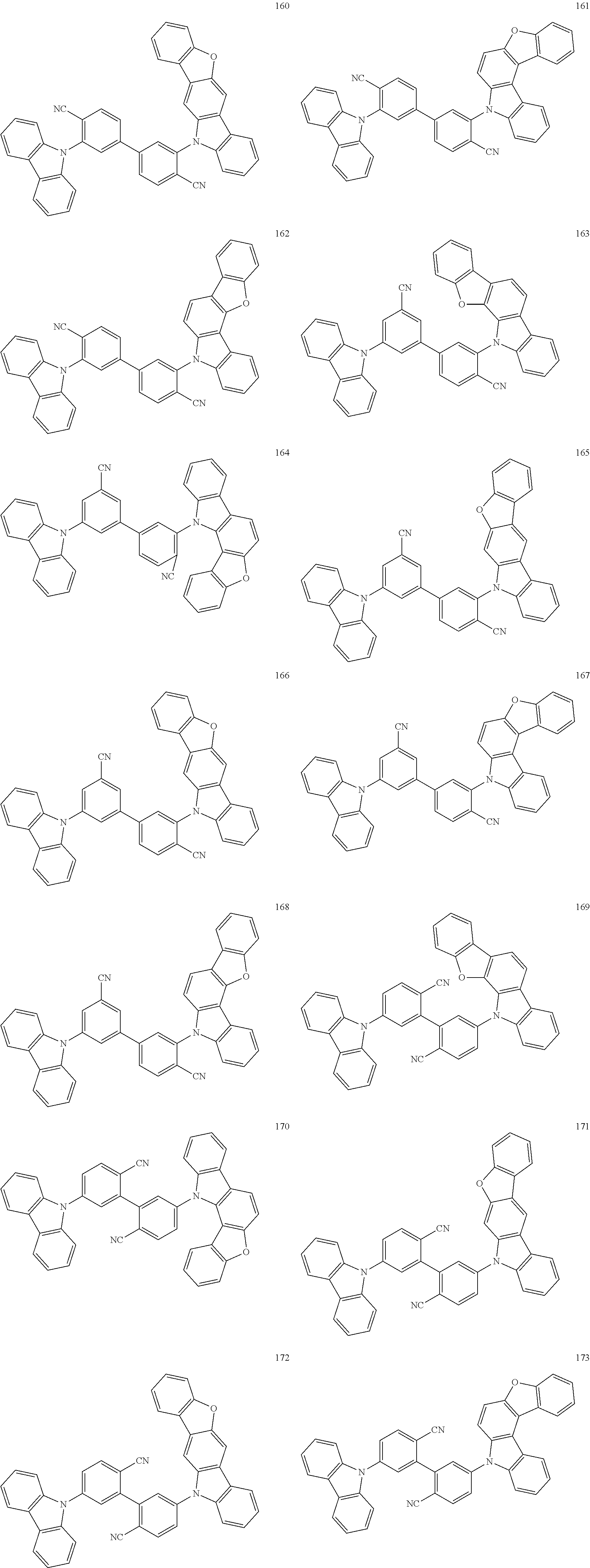

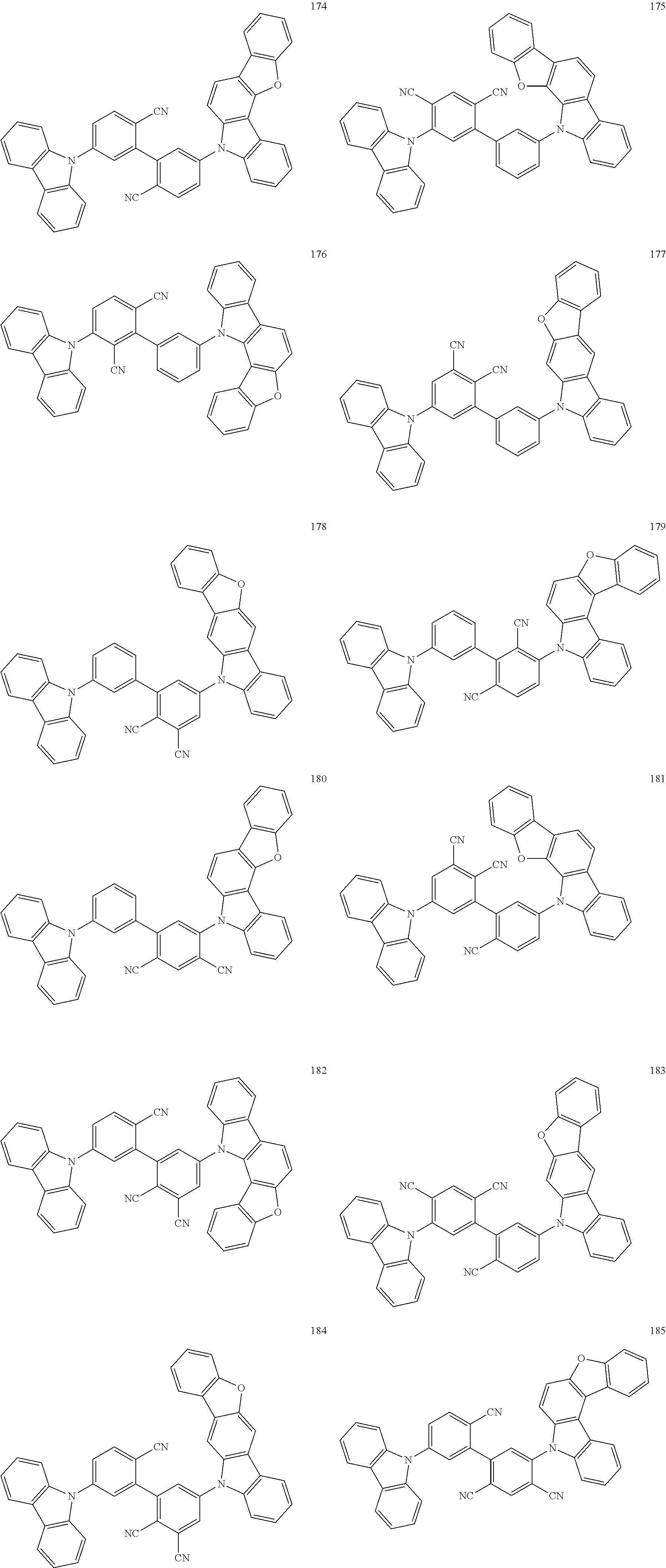

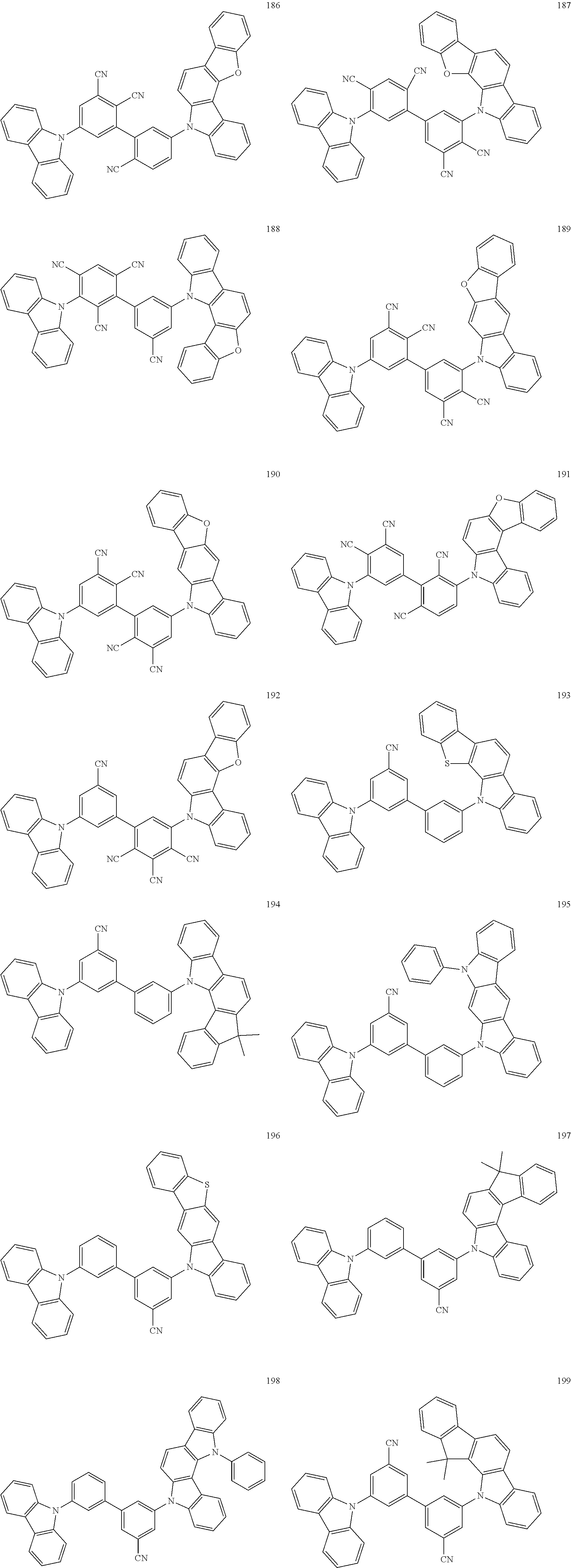

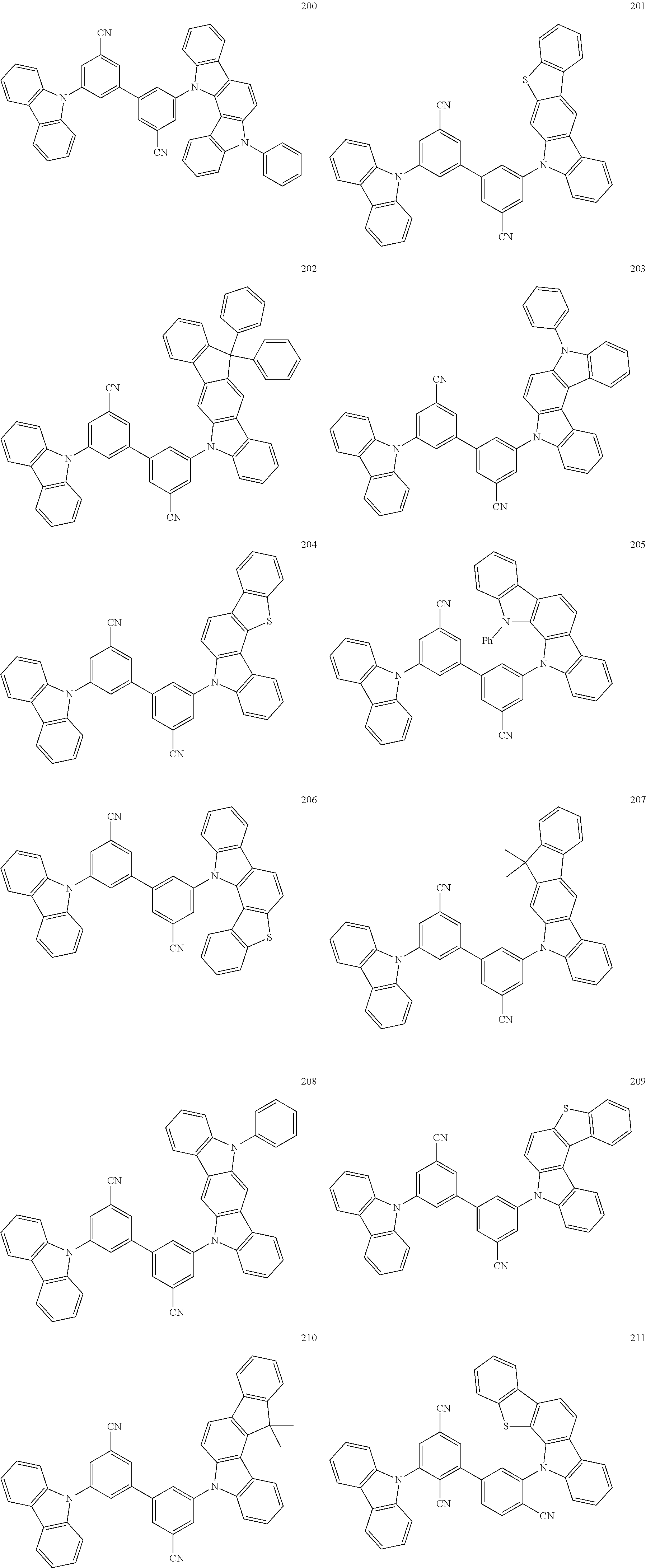

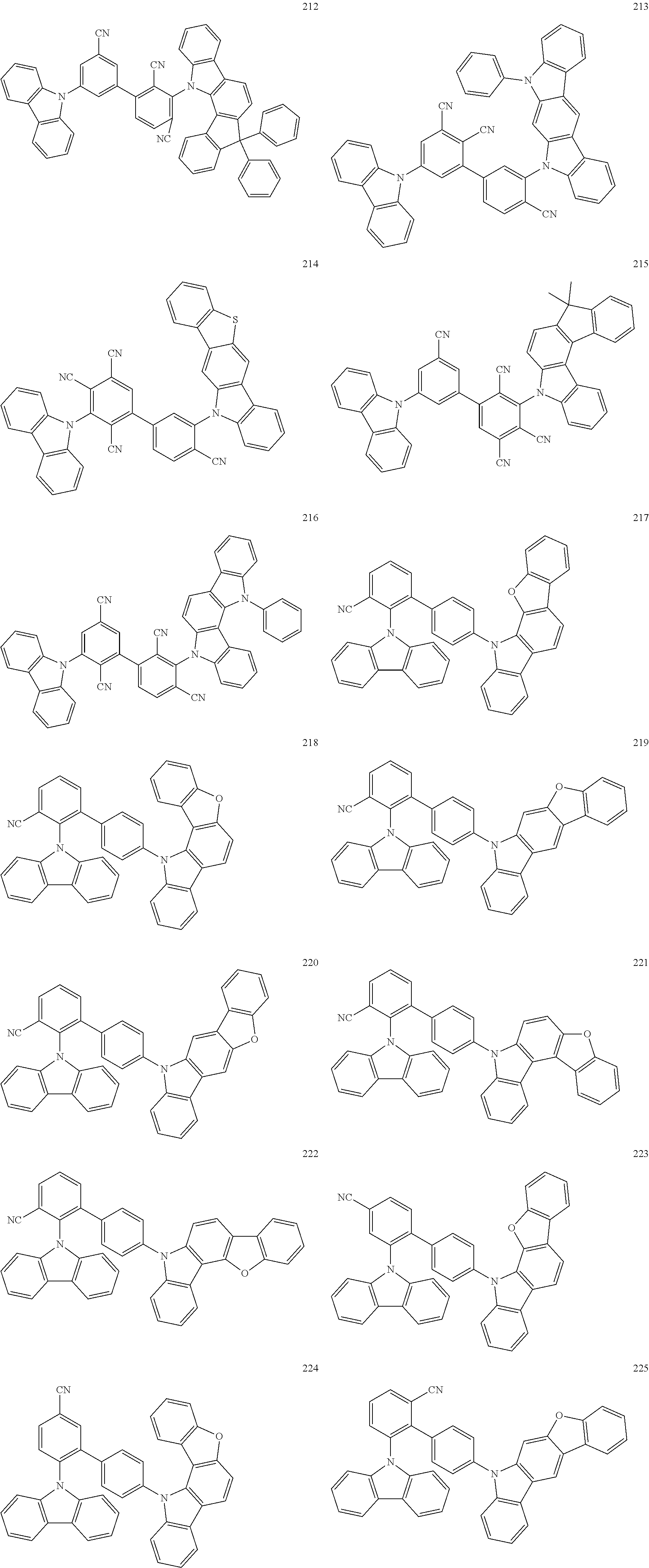

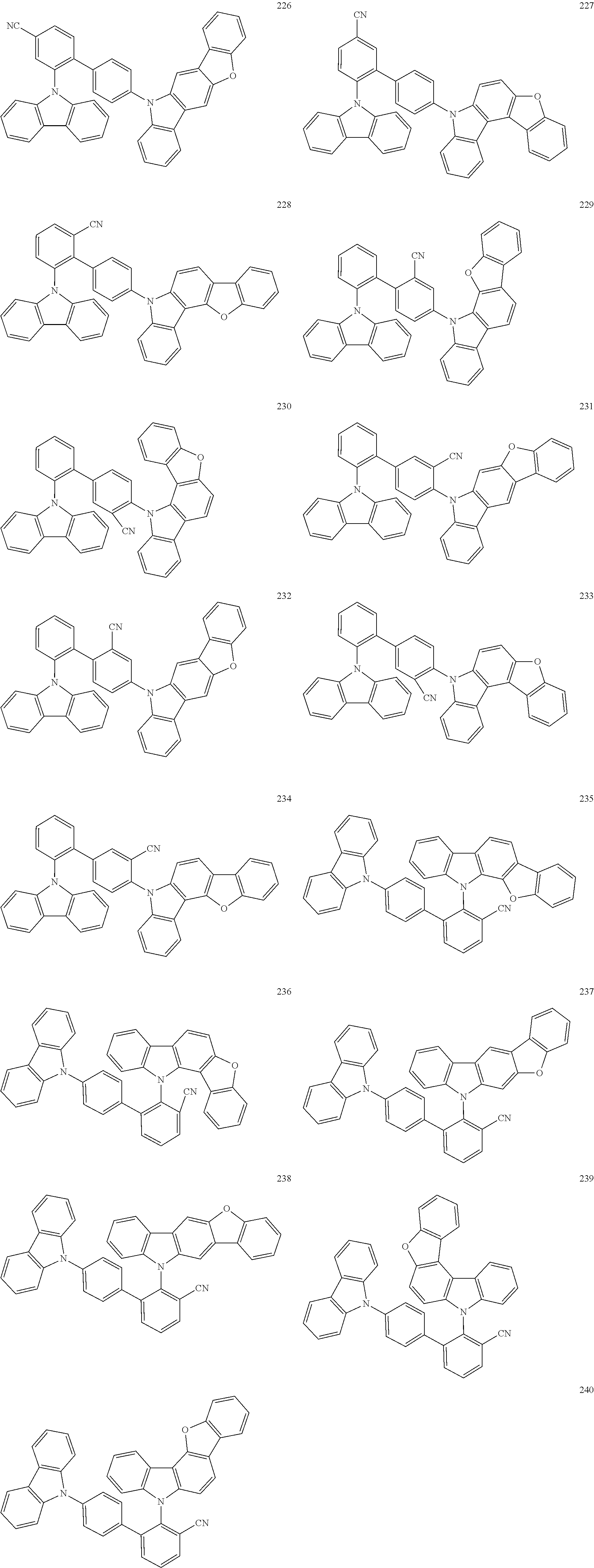

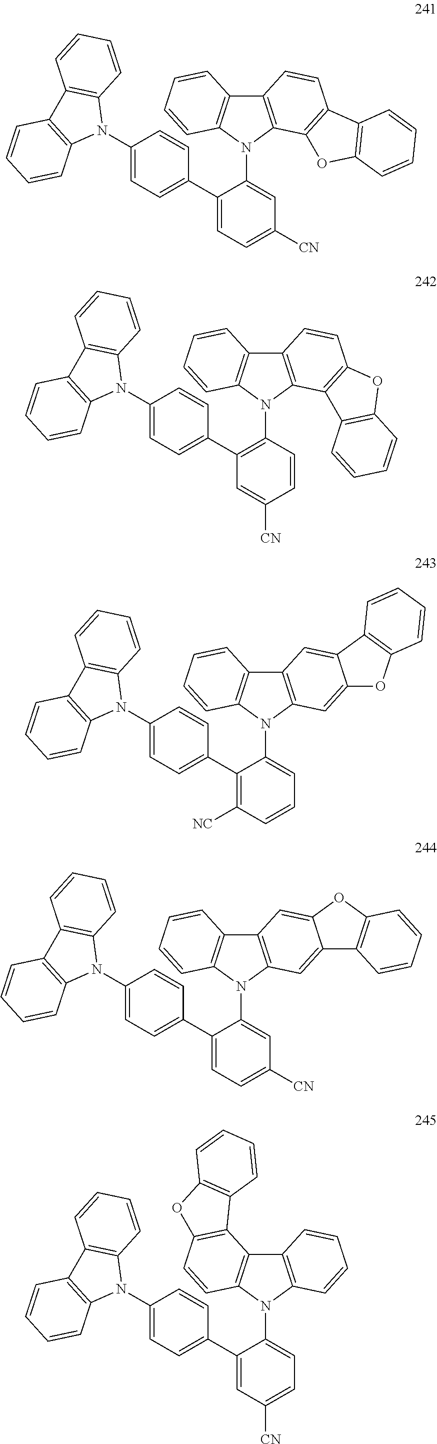 [SMILES: N#Cc1ccc(-c2ccc(-n3c4ccccc4c4ccccc43)cc2)c(-n2c3ccccc3c3ccc4c5ccccc5oc4c32)c1 ; N#Cc1ccc(-n2c3ccccc3c3ccc4oc5ccccc5c4c32)c(-c2ccc(-n3c4ccccc4c4ccccc43)cc2)c1 ; N#Cc1cccc(-n2c3ccccc3c3cc4c(cc32)oc2ccccc24)c1-c1ccc(-n2c3ccccc3c3ccccc32)cc1 ; N#Cc1ccc(-c2ccc(-n3c4ccccc4c4ccccc43)cc2)c(-n2c3ccccc3c3cc4oc5ccccc5c4cc32)c1 ; N#Cc1ccc(-n2c3ccccc3c3c4c(ccc32)oc2ccccc24)c(-c2ccc(-n3c4ccccc4c4ccccc43)cc2)c1]

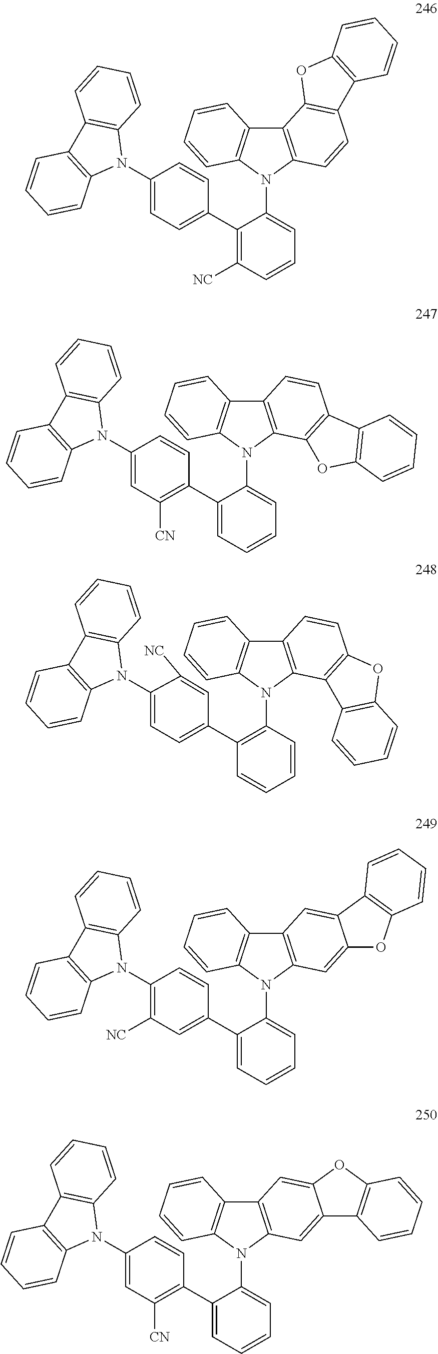 [SMILES: N#Cc1cccc(-n2c3ccccc3c3c4oc5ccccc5c4ccc32)c1-c1ccc(-n2c3ccccc3c3ccccc32)cc1 ; N#Cc1cc(-n2c3ccccc3c3ccccc32)ccc1-c1ccccc1-n1c2ccccc2c2ccc3c4ccccc4oc3c21 ; N#Cc1cc(-c2ccccc2-n2c3ccccc3c3ccc4oc5ccccc5c4c32)ccc1-n1c2ccccc2c2ccccc21 ; N#Cc1cc(-c2ccccc2-n2c3ccccc3c3cc4c(cc32)oc2ccccc24)ccc1-n1c2ccccc2c2ccccc21 ; N#Cc1cc(-n2c3ccccc3c3ccccc32)ccc1-c1ccccc1-n1c2ccccc2c2cc3oc4ccccc4c3cc21]

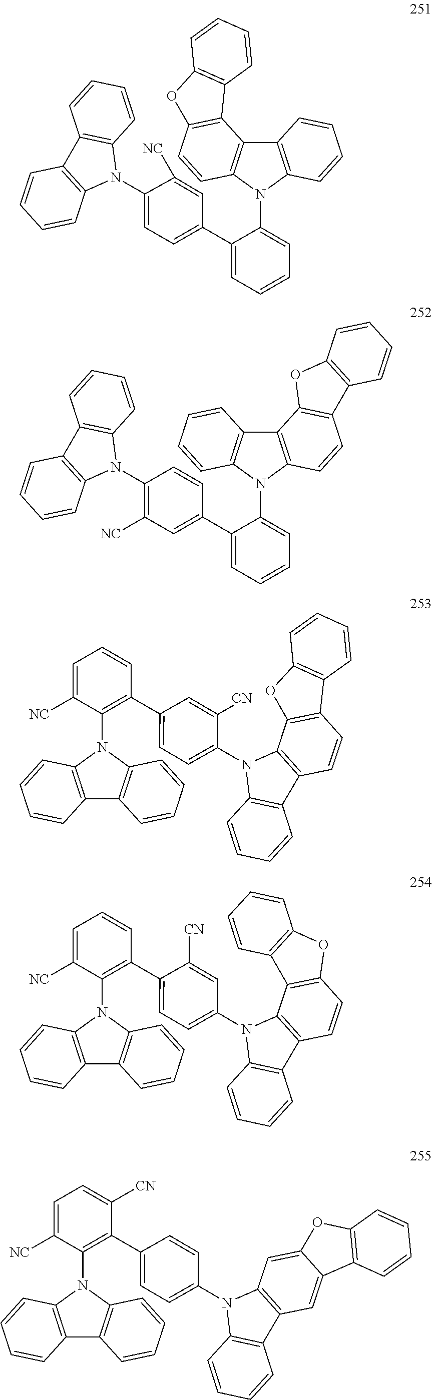

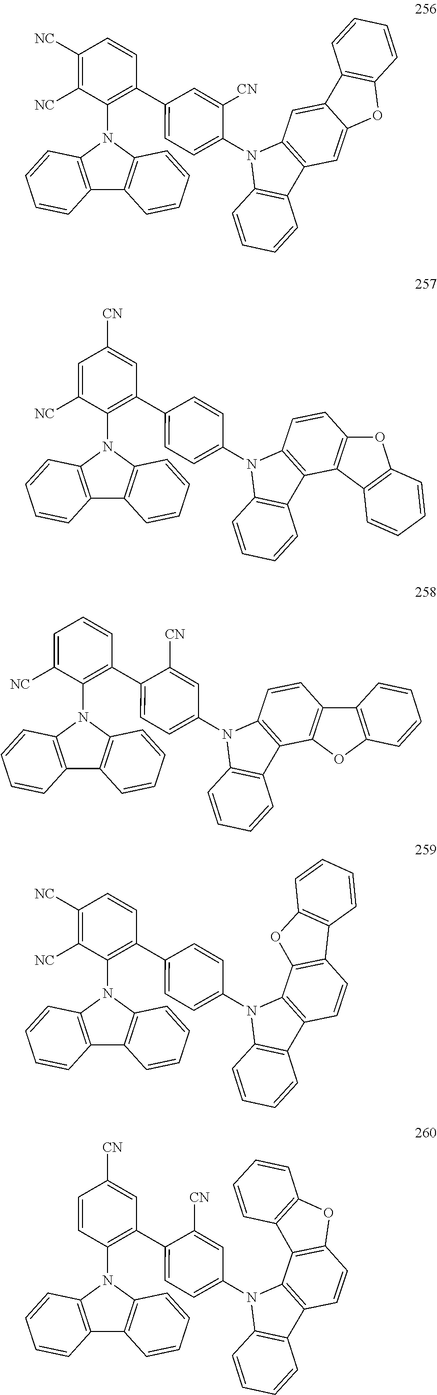

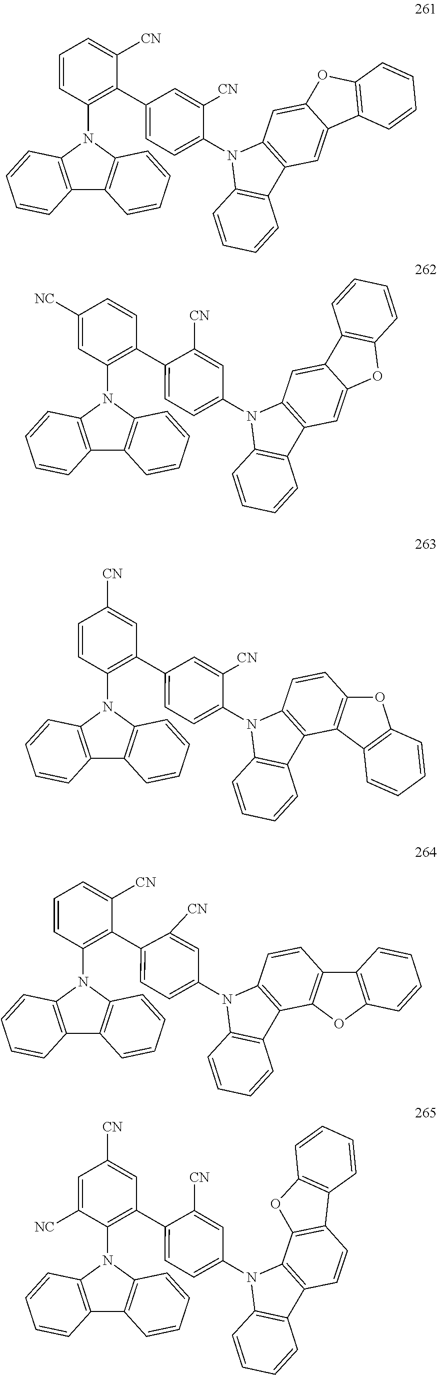

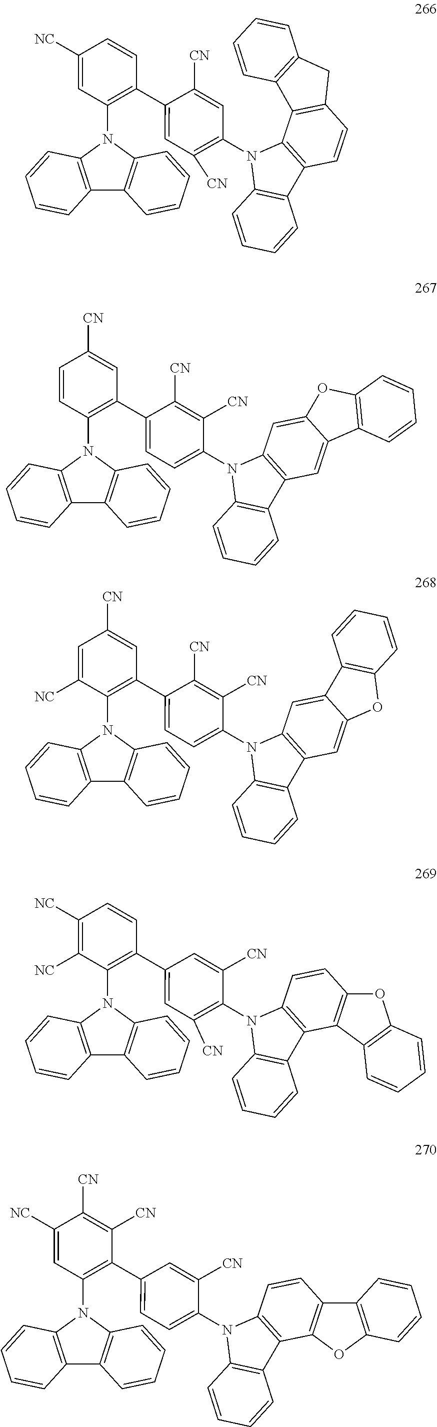 [SMILES: N#Cc1ccc(-c2cc(C#N)c(-n3c4ccccc4c4ccc5c(c43)-c3ccccc3C5)cc2C#N)c(-n2c3ccccc3c3ccccc32)c1 ; N#Cc1ccc(-n2c3ccccc3c3ccccc32)c(-c2ccc(-n3c4ccccc4c4cc5c(cc43)oc3ccccc35)c(C#N)c2C#N)c1 ; N#Cc1cc(C#N)c(-n2c3ccccc3c3ccccc32)c(-c2ccc(-n3c4ccccc4c4cc5oc6ccccc6c5cc43)c(C#N)c2C#N)c1 ; N#Cc1ccc(-c2cc(C#N)c(-n3c4ccccc4c4c5c(ccc43)oc3ccccc35)c(C#N)c2)c(-n2c3ccccc3c3ccccc32)c1C#N ; N#Cc1cc(-c2c(-n3c4ccccc4c4ccccc43)cc(C#N)c(C#N)c2C#N)ccc1-n1c2ccccc2c2c3oc4ccccc4c3ccc21]

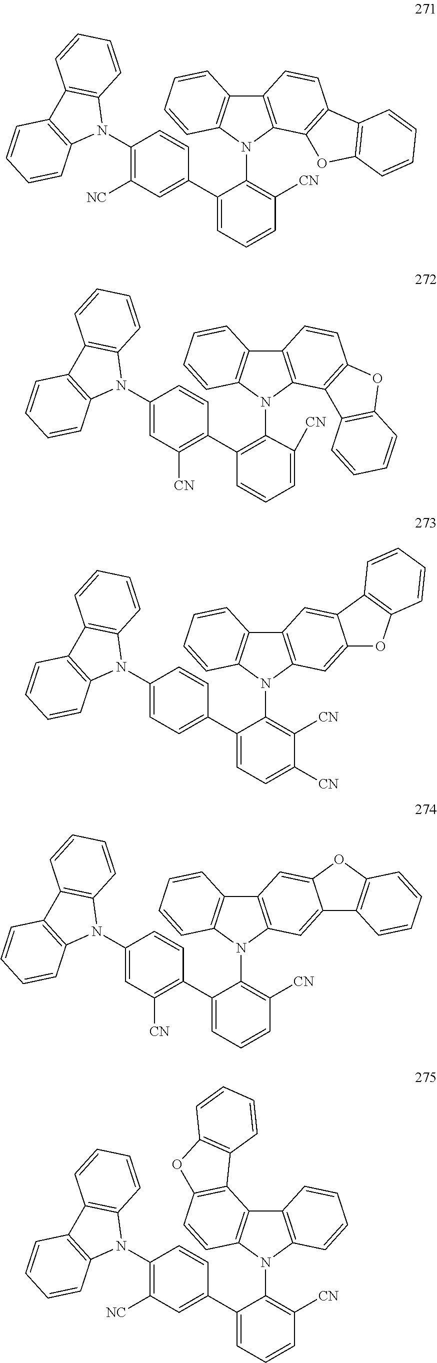

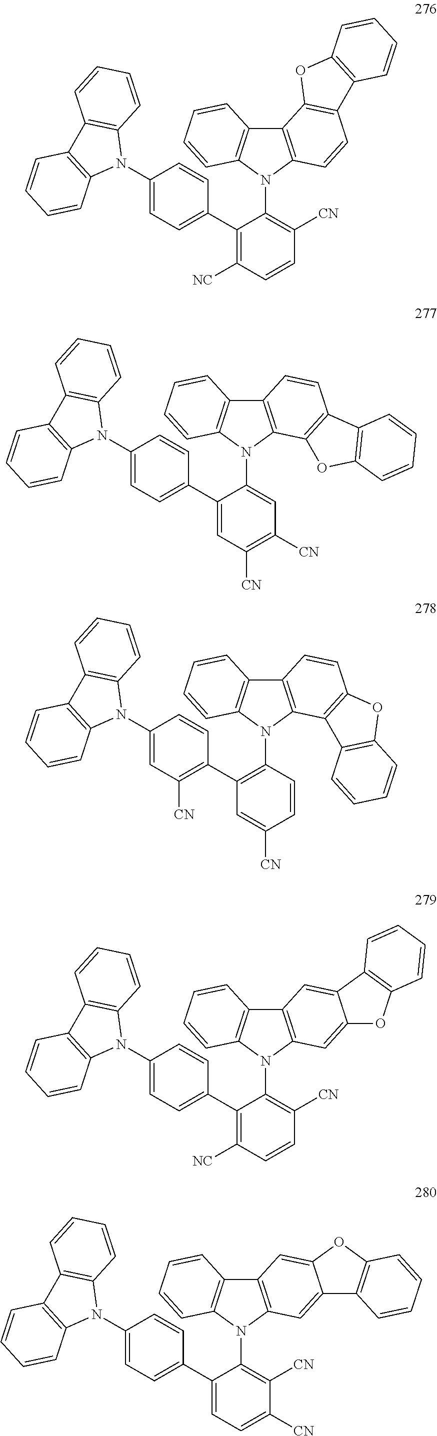 [SMILES: N#Cc1ccc(C#N)c(-n2c3ccccc3c3c4oc5ccccc5c4ccc32)c1-c1ccc(-n2c3ccccc3c3ccccc32)cc1 ; N#Cc1cc(-c2ccc(-n3c4ccccc4c4ccccc43)cc2)c(-n2c3ccccc3c3ccc4c5ccccc5oc4c32)cc1C#N ; N#Cc1ccc(-n2c3ccccc3c3ccc4oc5ccccc5c4c32)c(-c2ccc(-n3c4ccccc4c4ccccc43)cc2C#N)c1 ; N#Cc1ccc(C#N)c(-n2c3ccccc3c3cc4c(cc32)oc2ccccc24)c1-c1ccc(-n2c3ccccc3c3ccccc32)cc1 ; N#Cc1ccc(-c2ccc(-n3c4ccccc4c4ccccc43)cc2)c(-n2c3ccccc3c3cc4oc5ccccc5c4cc32)c1C#N]

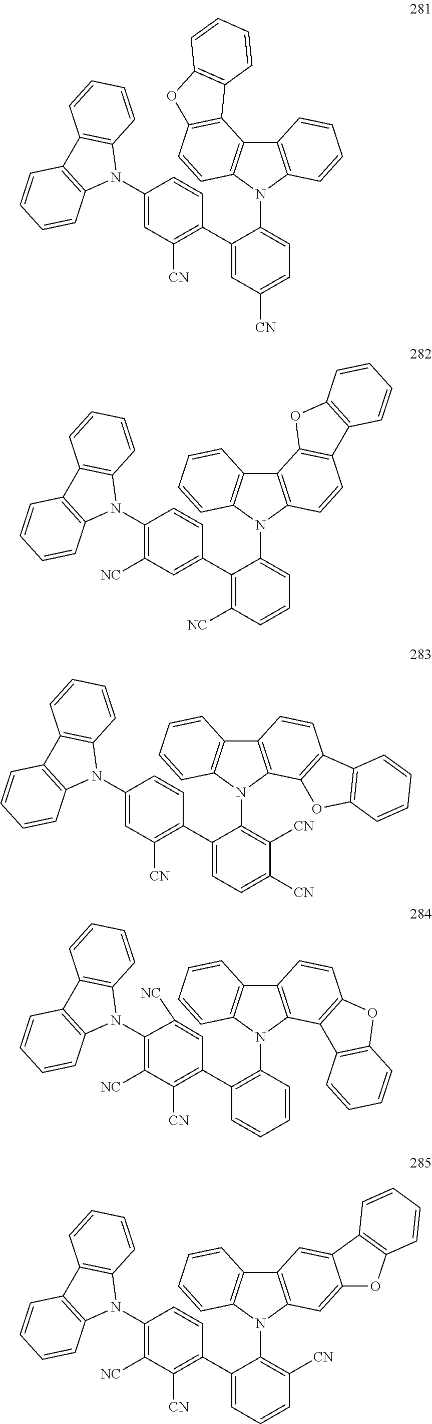 [SMILES: N#Cc1ccc(-n2c3ccccc3c3c4c(ccc32)oc2ccccc24)c(-c2ccc(-n3c4ccccc4c4ccccc43)cc2C#N)c1 ; N#Cc1cc(-c2c(C#N)cccc2-n2c3ccccc3c3c4oc5ccccc5c4ccc32)ccc1-n1c2ccccc2c2ccccc21 ; N#Cc1cc(-n2c3ccccc3c3ccccc32)ccc1-c1ccc(C#N)c(C#N)c1-n1c2ccccc2c2ccc3c4ccccc4oc3c21 ; N#Cc1cc(-c2ccccc2-n2c3ccccc3c3ccc4oc5ccccc5c4c32)c(C#N)c(C#N)c1-n1c2ccccc2c2ccccc21 ; N#Cc1cccc(-c2ccc(-n3c4ccccc4c4ccccc43)c(C#N)c2C#N)c1-n1c2ccccc2c2cc3c(cc21)oc1ccccc13]

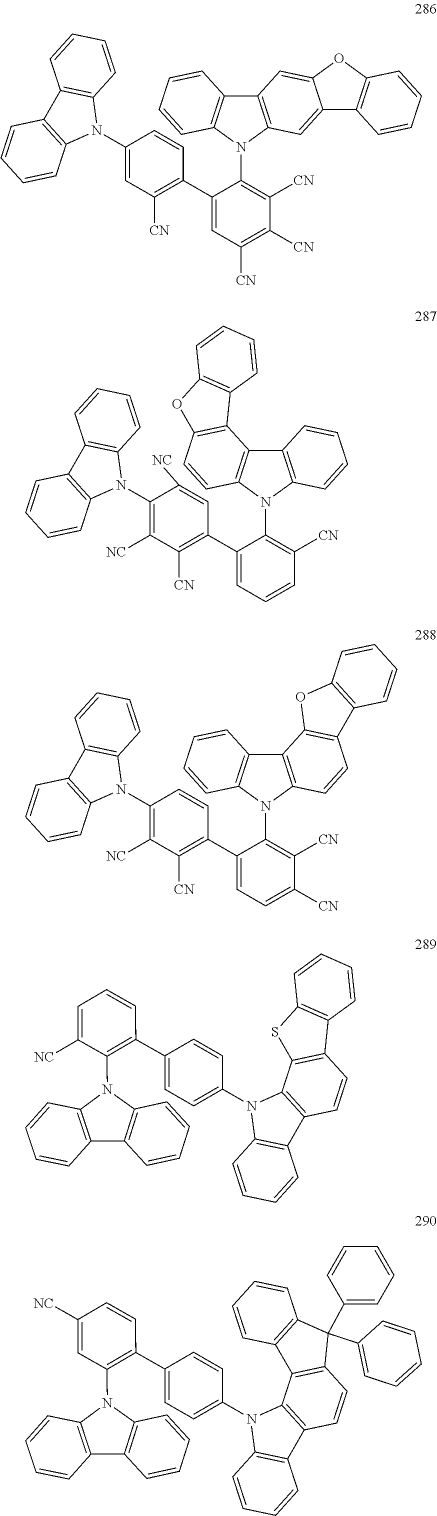

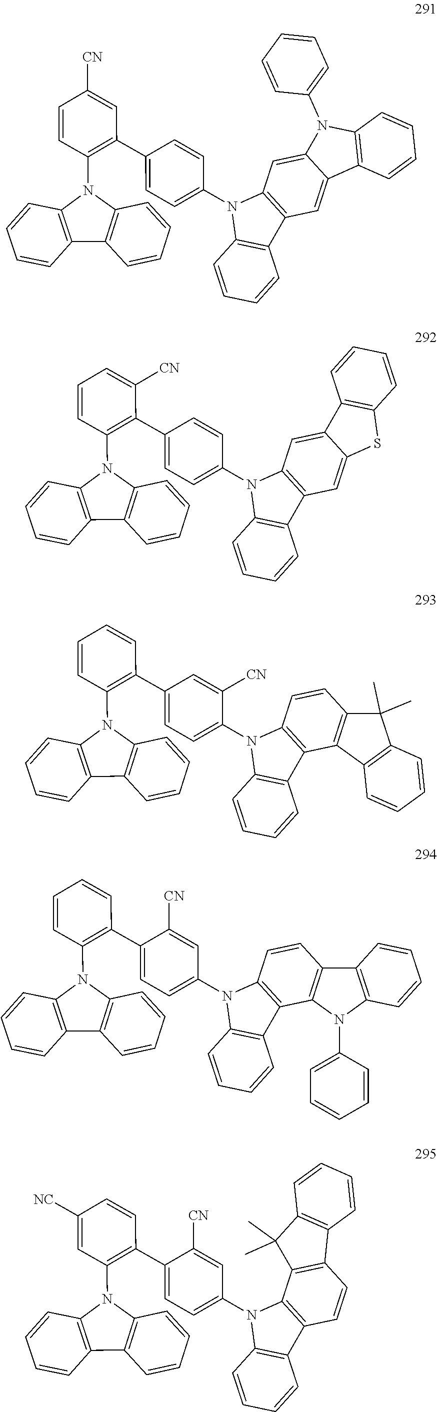 [SMILES: N#Cc1ccc(-n2c3ccccc3c3ccccc32)c(-c2ccc(-n3c4ccccc4c4cc5c6ccccc6n(-c6ccccc6)c5cc43)cc2)c1 ; N#Cc1cccc(-n2c3ccccc3c3ccccc32)c1-c1ccc(-n2c3ccccc3c3cc4sc5ccccc5c4cc32)cc1 ; CC1(C)c2ccccc2-c2c1ccc1c2c2ccccc2n1-c1ccc(-c2ccccc2-n2c3ccccc3c3ccccc32)cc1C#N ; N#Cc1cc(-n2c3ccccc3c3c2ccc2c4ccccc4n(-c4ccccc4)c23)ccc1-c1ccccc1-n1c2ccccc2c2ccccc21 ; CC1(C)c2ccccc2-c2ccc3c4ccccc4n(-c4ccc(-c5ccc(C#N)cc5-n5c6ccccc6c6ccccc65)c(C#N)c4)c3c21]

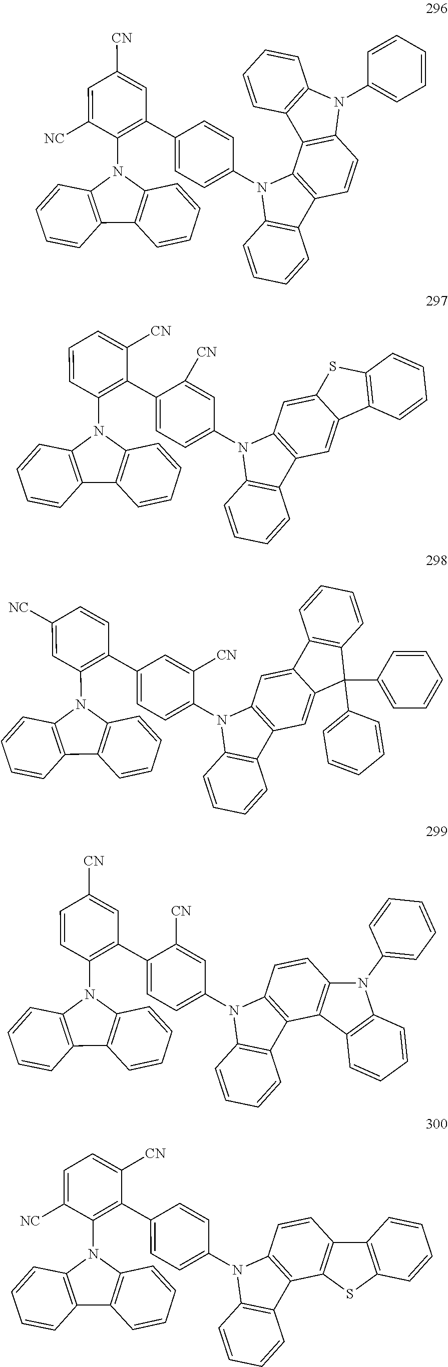 [SMILES: N#Cc1cc(C#N)c(-n2c3ccccc3c3ccccc32)c(-c2ccc(-n3c4ccccc4c4ccc5c(c6ccccc6n5-c5ccccc5)c43)cc2)c1 ; N#Cc1cc(-n2c3ccccc3c3cc4c(cc32)sc2ccccc24)ccc1-c1c(C#N)cccc1-n1c2ccccc2c2ccccc21 ; N#Cc1ccc(-c2ccc(-n3c4ccccc4c4cc5c(cc43)-c3ccccc3C5(c3ccccc3)c3ccccc3)c(C#N)c2)c(-n2c3ccccc3c3ccccc32)c1 ; N#Cc1ccc(-n2c3ccccc3c3ccccc32)c(-c2ccc(-n3c4ccccc4c4c5c6ccccc6n(-c6ccccc6)c5ccc43)cc2C#N)c1 ; N#Cc1ccc(C#N)c(-n2c3ccccc3c3ccccc32)c1-c1ccc(-n2c3ccccc3c3c4sc5ccccc5c4ccc32)cc1]

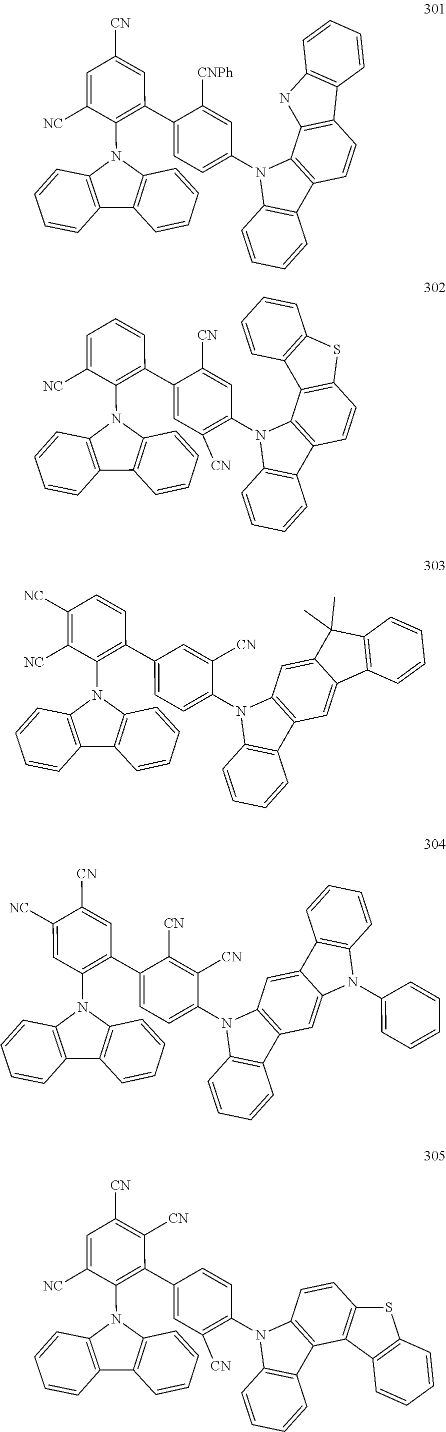

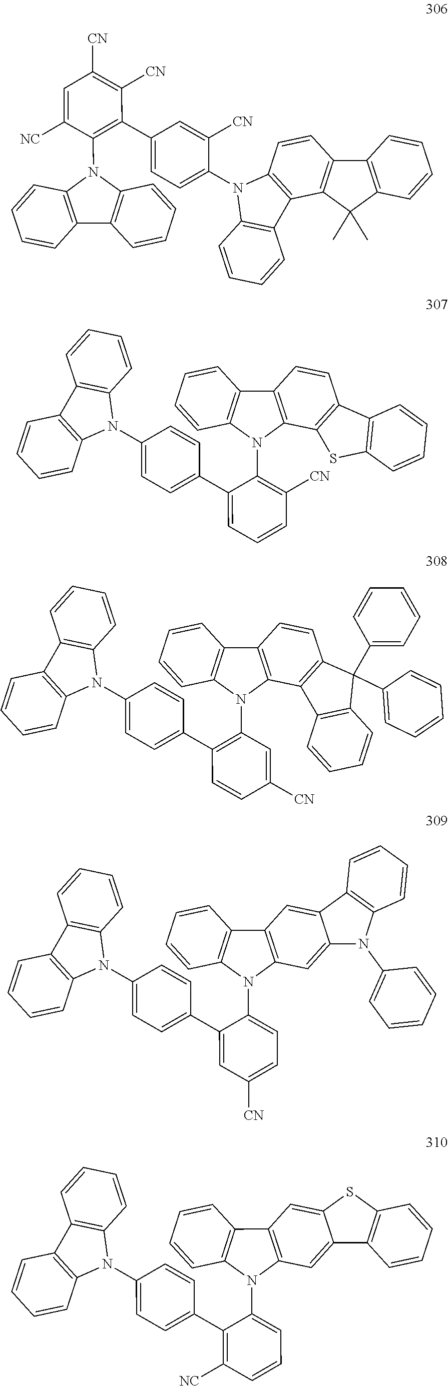 [SMILES: CC1(C)c2ccccc2-c2ccc3c(c21)c1ccccc1n3-c1ccc(-c2c(C#N)c(C#N)cc(C#N)c2-n2c3ccccc3c3ccccc32)cc1C#N ; N#Cc1cccc(-c2ccc(-n3c4ccccc4c4ccccc43)cc2)c1-n1c2ccccc2c2ccc3c4ccccc4sc3c21 ; N#Cc1ccc(-c2ccc(-n3c4ccccc4c4ccccc43)cc2)c(-n2c3ccccc3c3ccc4c(c32)-c2ccccc2C4(c2ccccc2)c2ccccc2)c1 ; N#Cc1ccc(-n2c3ccccc3c3cc4c5ccccc5n(-c5ccccc5)c4cc32)c(-c2ccc(-n3c4ccccc4c4ccccc43)cc2)c1 ; N#Cc1cccc(-n2c3ccccc3c3cc4sc5ccccc5c4cc32)c1-c1ccc(-n2c3ccccc3c3ccccc32)cc1]

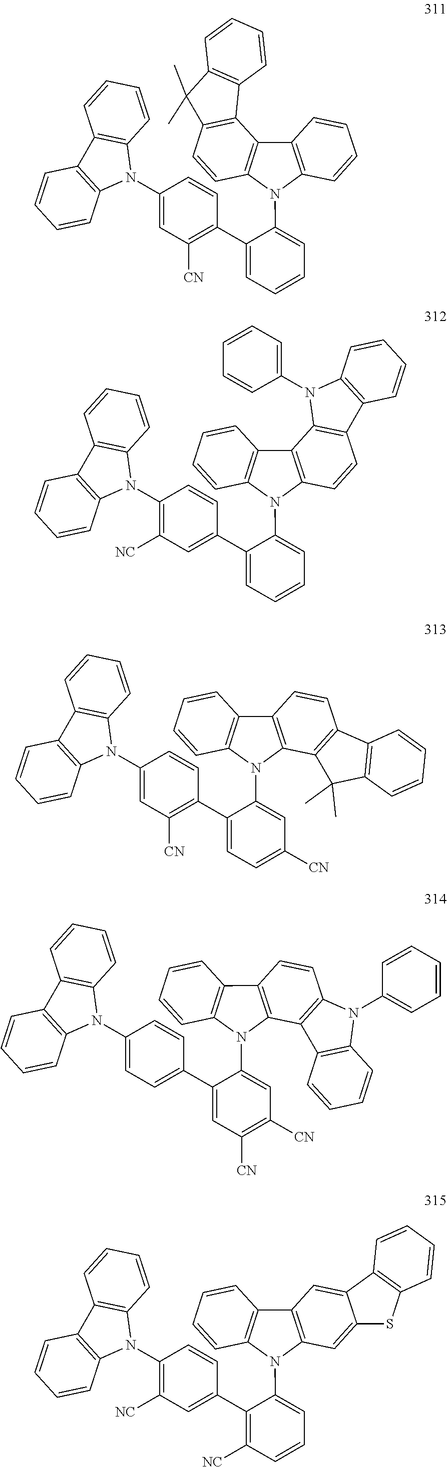

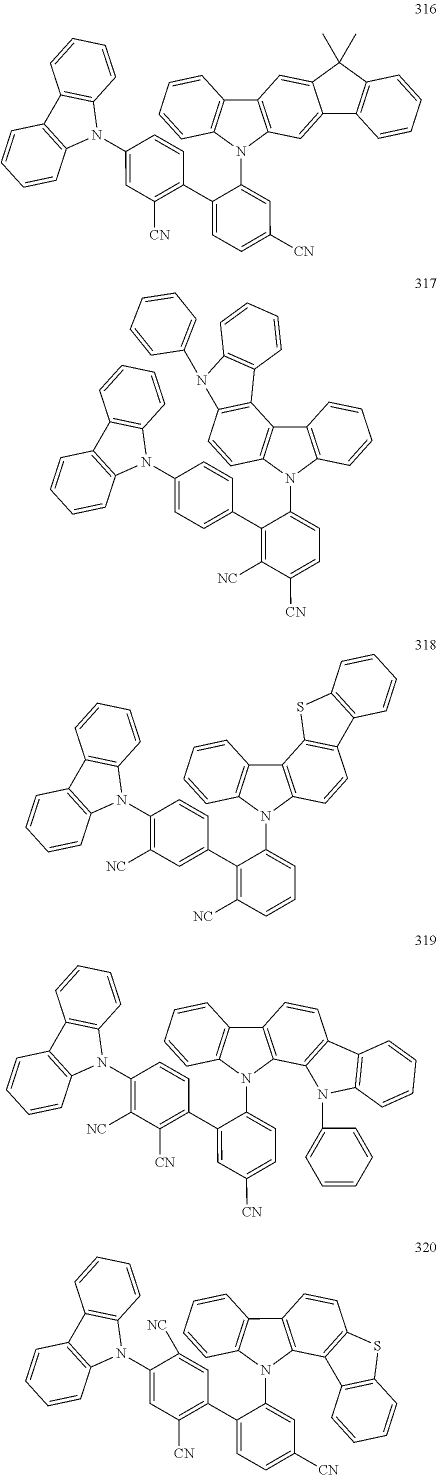 [SMILES: CC1(C)c2ccccc2-c2cc3c(cc21)c1ccccc1n3-c1cc(C#N)ccc1-c1ccc(-n2c3ccccc3c3ccccc32)cc1C#N ; N#Cc1ccc(-n2c3ccccc3c3c4c5ccccc5n(-c5ccccc5)c4ccc32)c(-c2ccc(-n3c4ccccc4c4ccccc43)cc2)c1C#N ; N#Cc1cc(-c2c(C#N)cccc2-n2c3ccccc3c3c4sc5ccccc5c4ccc32)ccc1-n1c2ccccc2c2ccccc21 ; N#Cc1ccc(-n2c3ccccc3c3ccc4c5ccccc5n(-c5ccccc5)c4c32)c(-c2ccc(-n3c4ccccc4c4ccccc43)c(C#N)c2C#N)c1 ; N#Cc1ccc(-c2cc(C#N)c(-n3c4ccccc4c4ccccc43)cc2C#N)c(-n2c3ccccc3c3ccc4sc5ccccc5c4c32)c1]

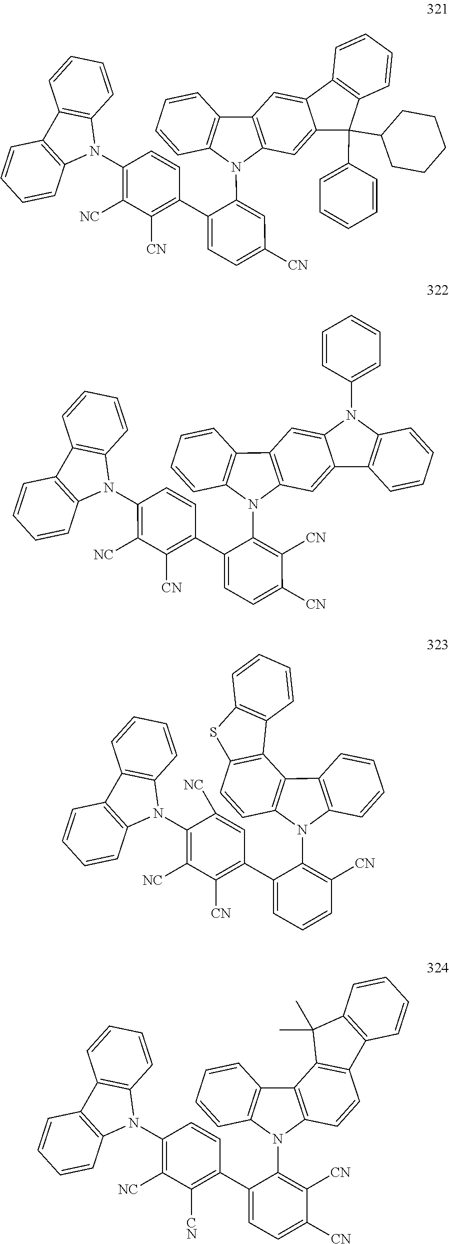 [SMILES: N#Cc1ccc(-c2ccc(-n3c4ccccc4c4ccccc43)c(C#N)c2C#N)c(-n2c3ccccc3c3cc4c(cc32)C(c2ccccc2)(C2CCCCC2)c2ccccc2-4)c1 ; N#Cc1ccc(-c2ccc(-n3c4ccccc4c4ccccc43)c(C#N)c2C#N)c(-n2c3ccccc3c3cc4c(cc32)c2ccccc2n4-c2ccccc2)c1C#N ; N#Cc1cc(-c2cccc(C#N)c2-n2c3ccccc3c3c4c(ccc32)sc2ccccc24)c(C#N)c(C#N)c1-n1c2ccccc2c2ccccc21 ; CC1(C)c2ccccc2-c2ccc3c(c21)c1ccccc1n3-c1c(-c2ccc(-n3c4ccccc4c4ccccc43)c(C#N)c2C#N)ccc(C#N)c1C#N]

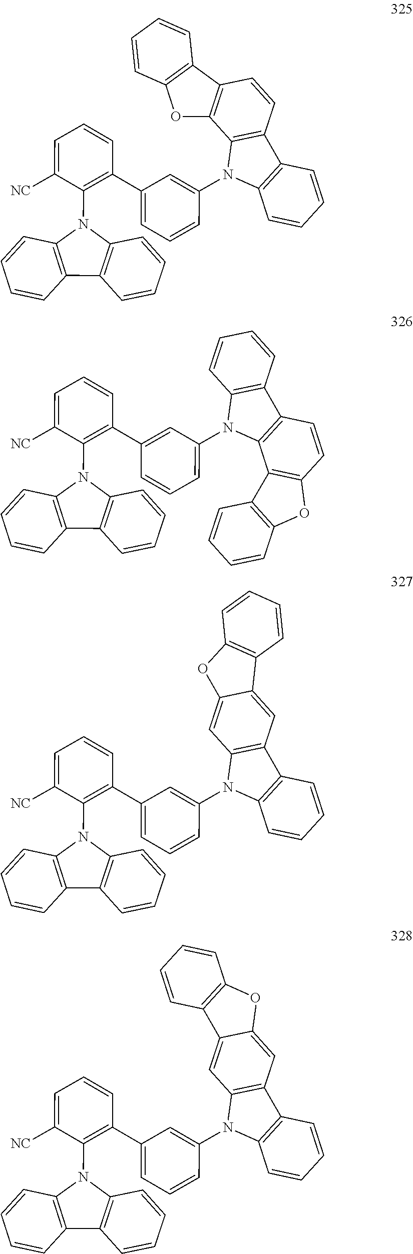

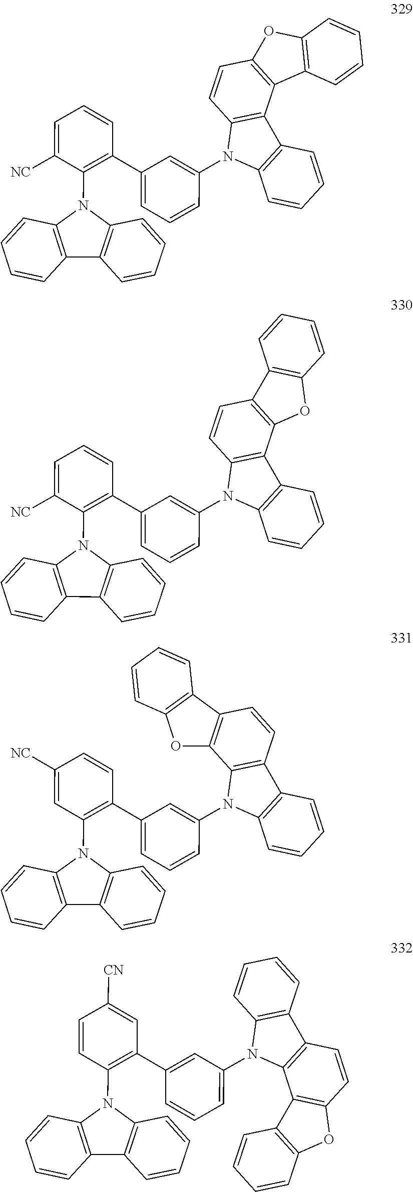

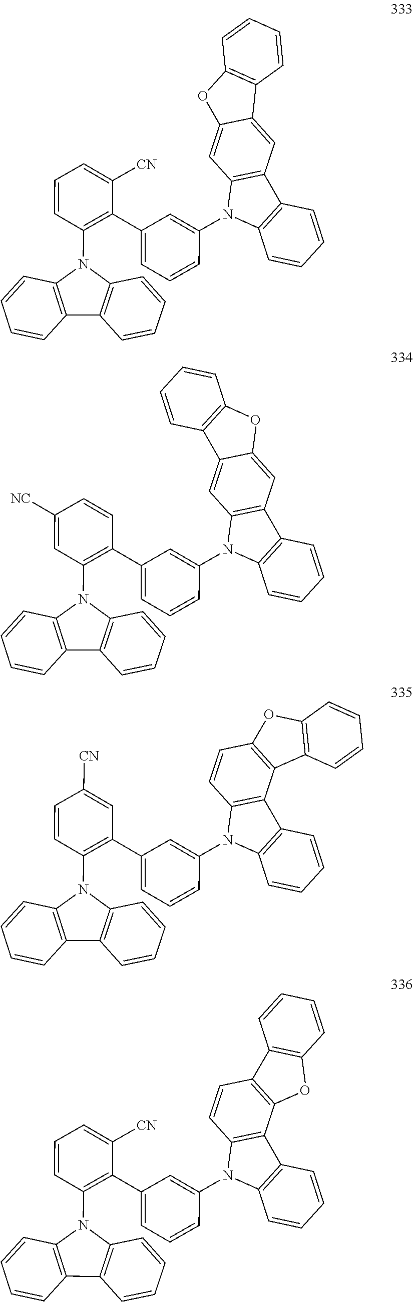

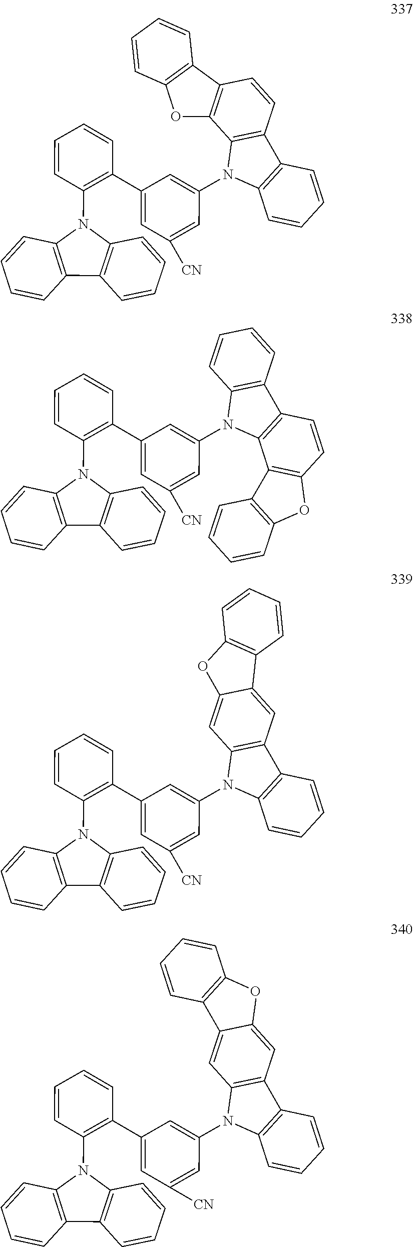

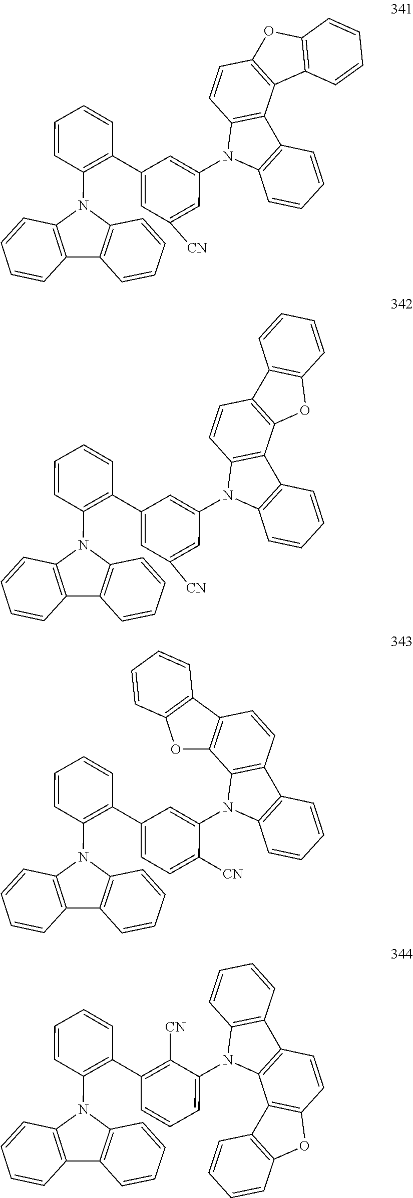

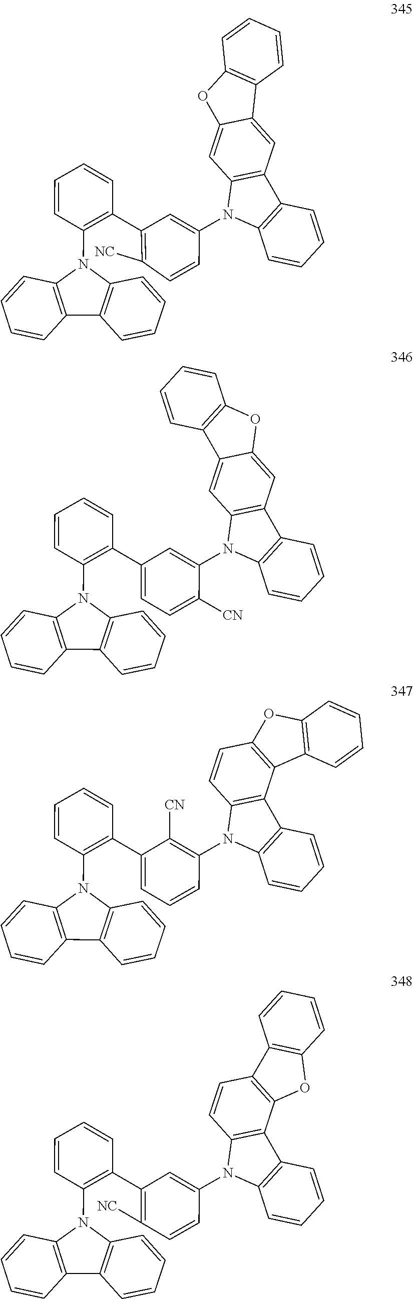

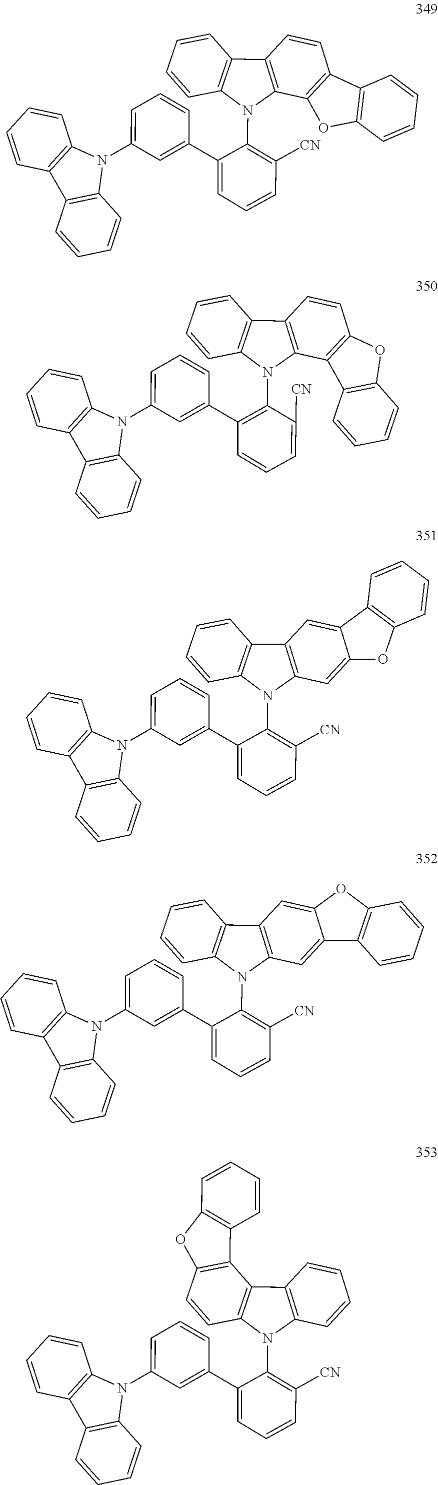 [SMILES: N#Cc1cccc(-c2cccc(-n3c4ccccc4c4ccccc43)c2)c1-n1c2ccccc2c2ccc3c4ccccc4oc3c21 ; N#Cc1cccc(-c2cccc(-n3c4ccccc4c4ccccc43)c2)c1-n1c2ccccc2c2ccc3oc4ccccc4c3c21 ; N#Cc1cccc(-c2cccc(-n3c4ccccc4c4ccccc43)c2)c1-n1c2ccccc2c2cc3c(cc21)oc1ccccc13 ; N#Cc1cccc(-c2cccc(-n3c4ccccc4c4ccccc43)c2)c1-n1c2ccccc2c2cc3oc4ccccc4c3cc21 ; N#Cc1cccc(-c2cccc(-n3c4ccccc4c4ccccc43)c2)c1-n1c2ccccc2c2c3c(ccc21)oc1ccccc13]

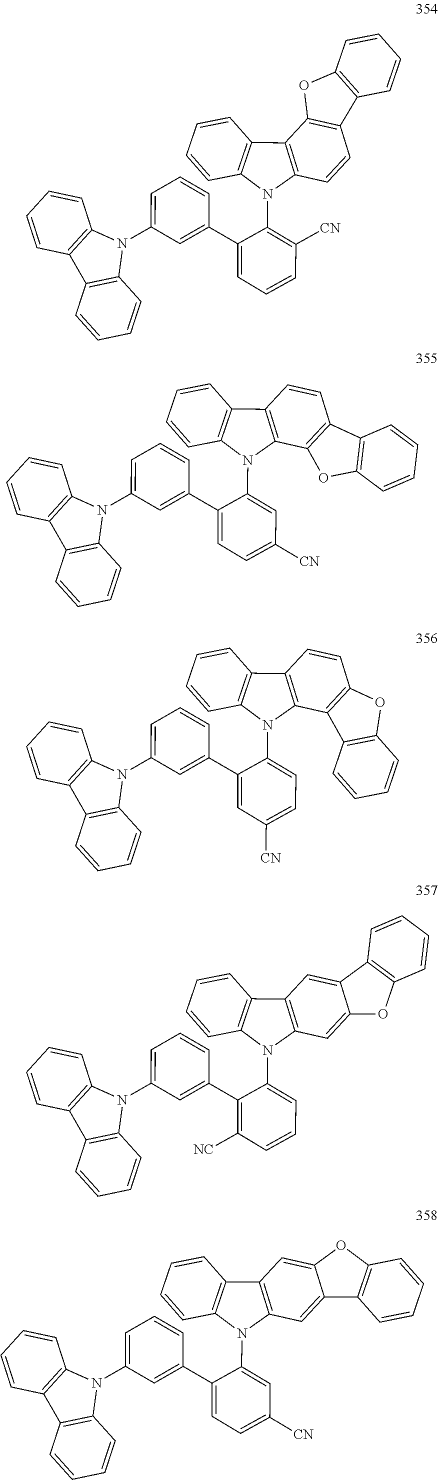 [SMILES: N#Cc1cccc(-c2cccc(-n3c4ccccc4c4ccccc43)c2)c1-n1c2ccccc2c2c3oc4ccccc4c3ccc21 ; N#Cc1ccc(-c2cccc(-n3c4ccccc4c4ccccc43)c2)c(-n2c3ccccc3c3ccc4c5ccccc5oc4c32)c1 ; N#Cc1ccc(-n2c3ccccc3c3ccc4oc5ccccc5c4c32)c(-c2cccc(-n3c4ccccc4c4ccccc43)c2)c1 ; N#Cc1cccc(-n2c3ccccc3c3cc4c(cc32)oc2ccccc24)c1-c1cccc(-n2c3ccccc3c3ccccc32)c1 ; N#Cc1ccc(-c2cccc(-n3c4ccccc4c4ccccc43)c2)c(-n2c3ccccc3c3cc4oc5ccccc5c4cc32)c1]

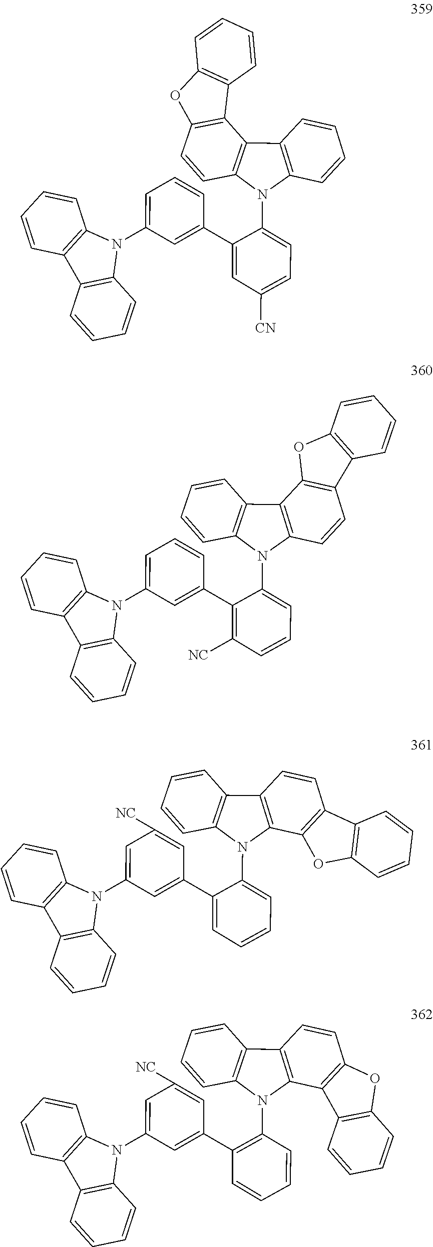 [SMILES: N#Cc1ccc(-n2c3ccccc3c3c4c(ccc32)oc2ccccc24)c(-c2cccc(-n3c4ccccc4c4ccccc43)c2)c1 ; N#Cc1cccc(-n2c3ccccc3c3c4oc5ccccc5c4ccc32)c1-c1cccc(-n2c3ccccc3c3ccccc32)c1 ; N#Cc1cc(-c2ccccc2-n2c3ccccc3c3ccc4c5ccccc5oc4c32)cc(-n2c3ccccc3c3ccccc32)c1 ; N#Cc1cc(-c2ccccc2-n2c3ccccc3c3ccc4oc5ccccc5c4c32)cc(-n2c3ccccc3c3ccccc32)c1]

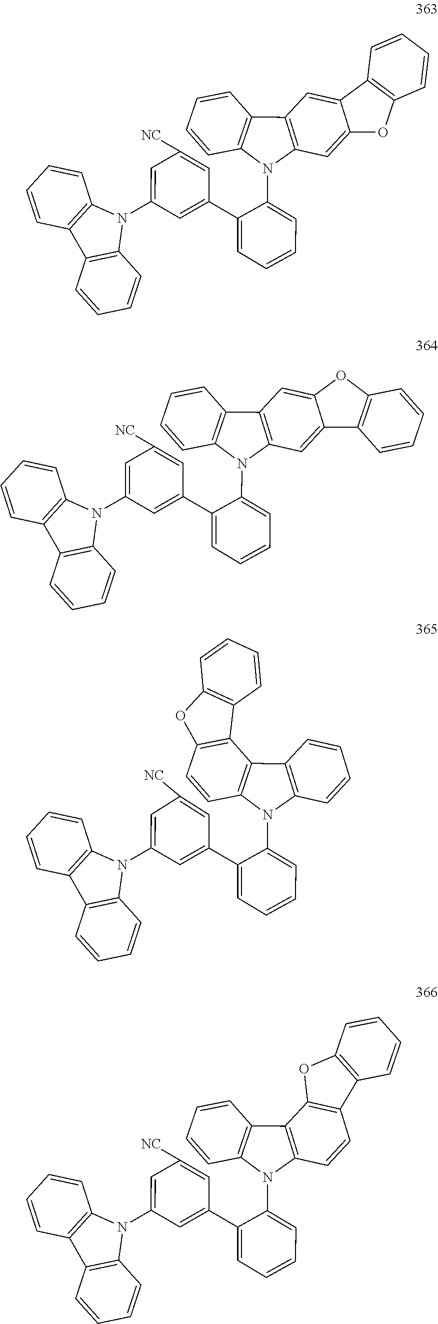 [SMILES: N#Cc1cc(-c2ccccc2-n2c3ccccc3c3cc4c(cc32)oc2ccccc24)cc(-n2c3ccccc3c3ccccc32)c1 ; N#Cc1cc(-c2ccccc2-n2c3ccccc3c3cc4oc5ccccc5c4cc32)cc(-n2c3ccccc3c3ccccc32)c1 ; N#Cc1cc(-c2ccccc2-n2c3ccccc3c3c4c(ccc32)oc2ccccc24)cc(-n2c3ccccc3c3ccccc32)c1 ; N#Cc1cc(-c2ccccc2-n2c3ccccc3c3c4oc5ccccc5c4ccc32)cc(-n2c3ccccc3c3ccccc32)c1]

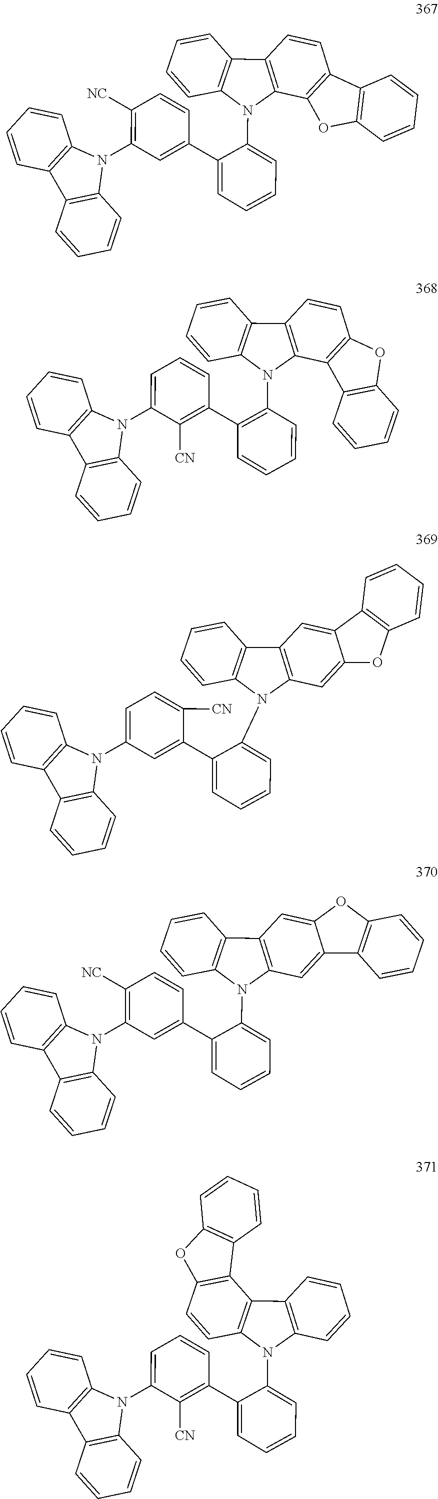 [SMILES: N#Cc1ccc(-c2ccccc2-n2c3ccccc3c3ccc4c5ccccc5oc4c32)cc1-n1c2ccccc2c2ccccc21 ; N#Cc1c(-c2ccccc2-n2c3ccccc3c3ccc4oc5ccccc5c4c32)cccc1-n1c2ccccc2c2ccccc21 ; N#Cc1ccc(-n2c3ccccc3c3ccccc32)cc1-c1ccccc1-n1c2ccccc2c2cc3c(cc21)oc1ccccc13 ; N#Cc1ccc(-c2ccccc2-n2c3ccccc3c3cc4oc5ccccc5c4cc32)cc1-n1c2ccccc2c2ccccc21 ; N#Cc1c(-c2ccccc2-n2c3ccccc3c3c4c(ccc32)oc2ccccc24)cccc1-n1c2ccccc2c2ccccc21]

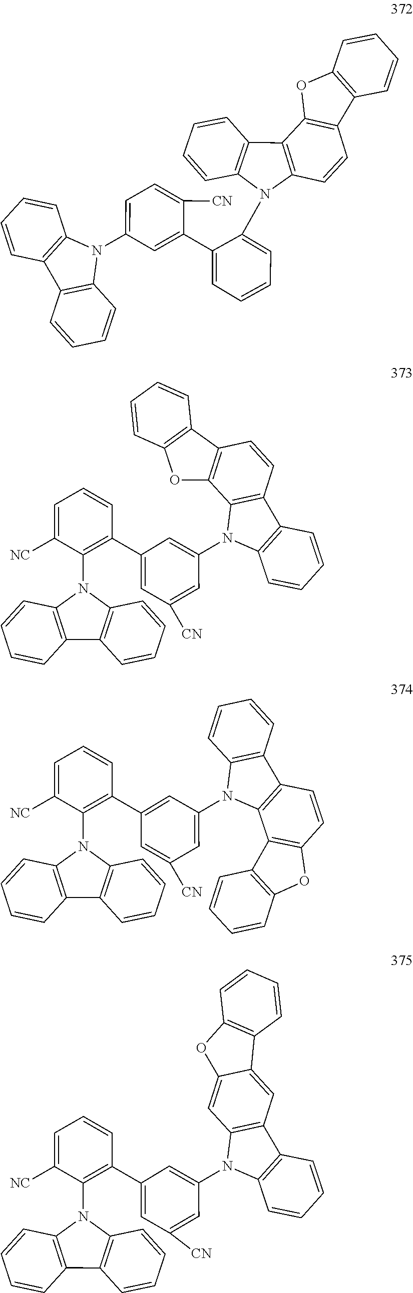

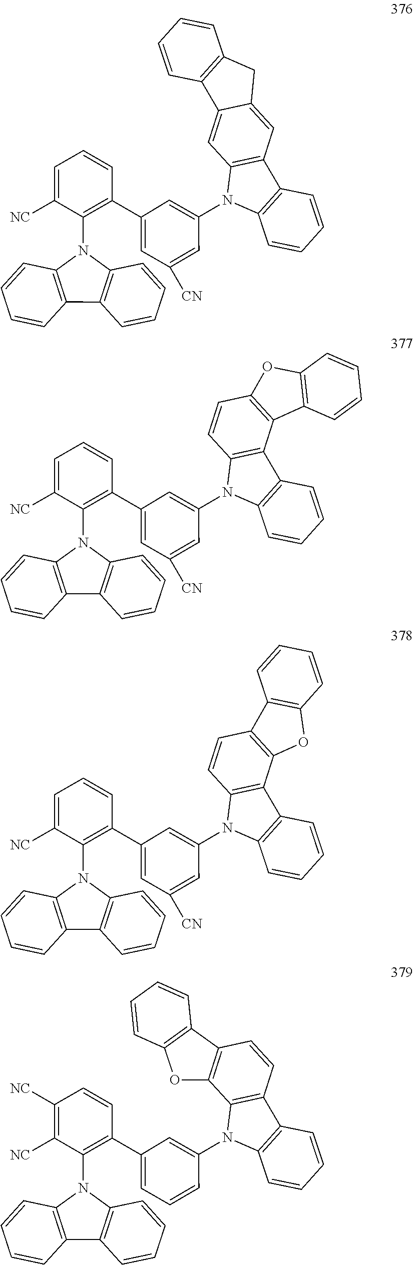

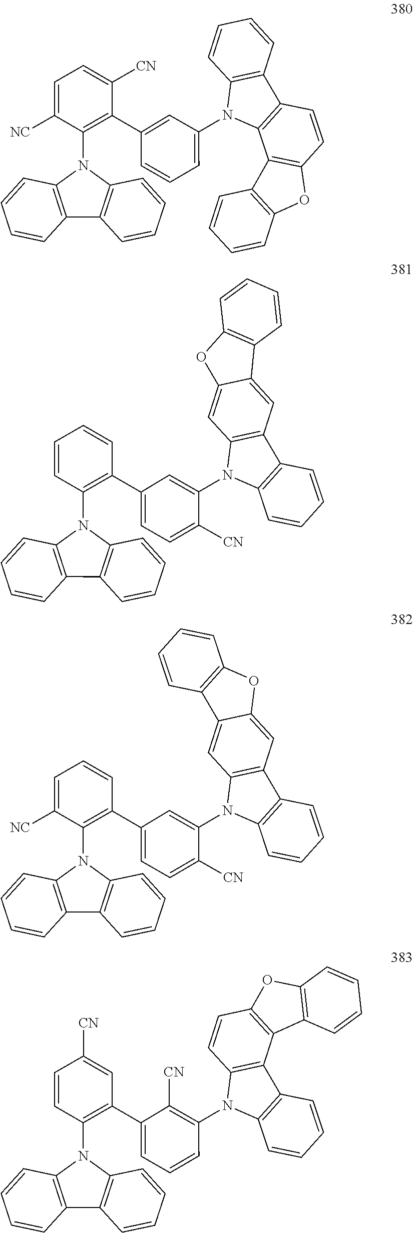

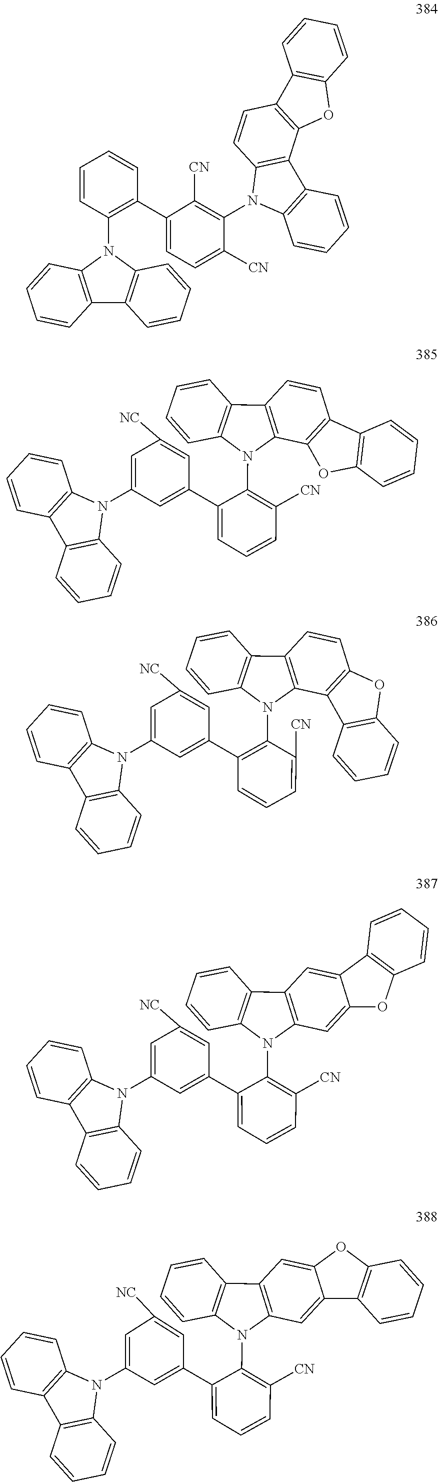 [SMILES: N#Cc1ccc(-c2ccccc2-n2c3ccccc3c3ccccc32)c(C#N)c1-n1c2ccccc2c2c3oc4ccccc4c3ccc21 ; N#Cc1cc(-c2cccc(C#N)c2-n2c3ccccc3c3ccc4c5ccccc5oc4c32)cc(-n2c3ccccc3c3ccccc32)c1 ; N#Cc1cc(-c2cccc(C#N)c2-n2c3ccccc3c3ccc4oc5ccccc5c4c32)cc(-n2c3ccccc3c3ccccc32)c1 ; N#Cc1cc(-c2cccc(C#N)c2-n2c3ccccc3c3cc4c(cc32)oc2ccccc24)cc(-n2c3ccccc3c3ccccc32)c1 ; N#Cc1cc(-c2cccc(C#N)c2-n2c3ccccc3c3cc4oc5ccccc5c4cc32)cc(-n2c3ccccc3c3ccccc32)c1]

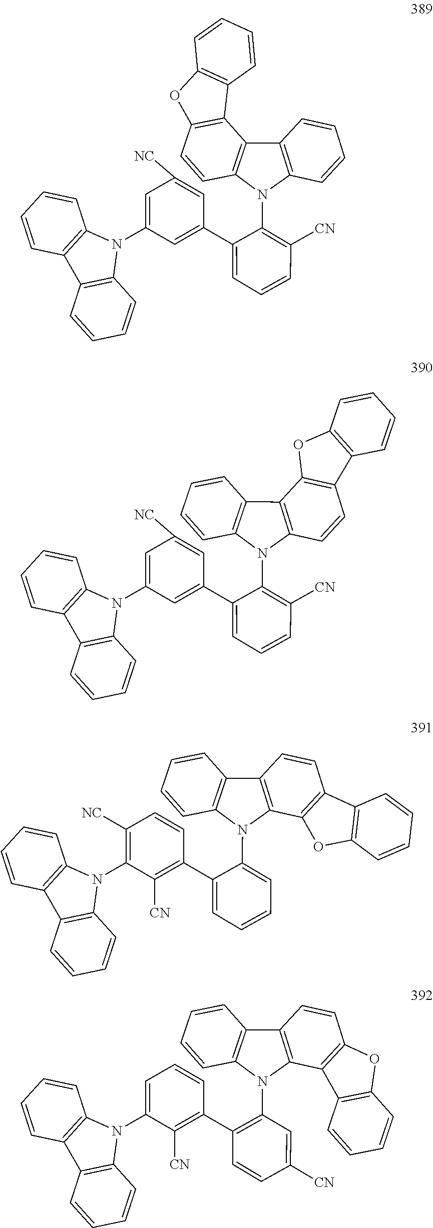 [SMILES: N#Cc1cc(-c2cccc(C#N)c2-n2c3ccccc3c3c4c(ccc32)oc2ccccc24)cc(-n2c3ccccc3c3ccccc32)c1 ; N#Cc1cc(-c2cccc(C#N)c2-n2c3ccccc3c3c4oc5ccccc5c4ccc32)cc(-n2c3ccccc3c3ccccc32)c1 ; N#Cc1ccc(-c2ccccc2-n2c3ccccc3c3ccc4c5ccccc5oc4c32)c(C#N)c1-n1c2ccccc2c2ccccc21 ; N#Cc1ccc(-c2cccc(-n3c4ccccc4c4ccccc43)c2C#N)c(-n2c3ccccc3c3ccc4oc5ccccc5c4c32)c1]

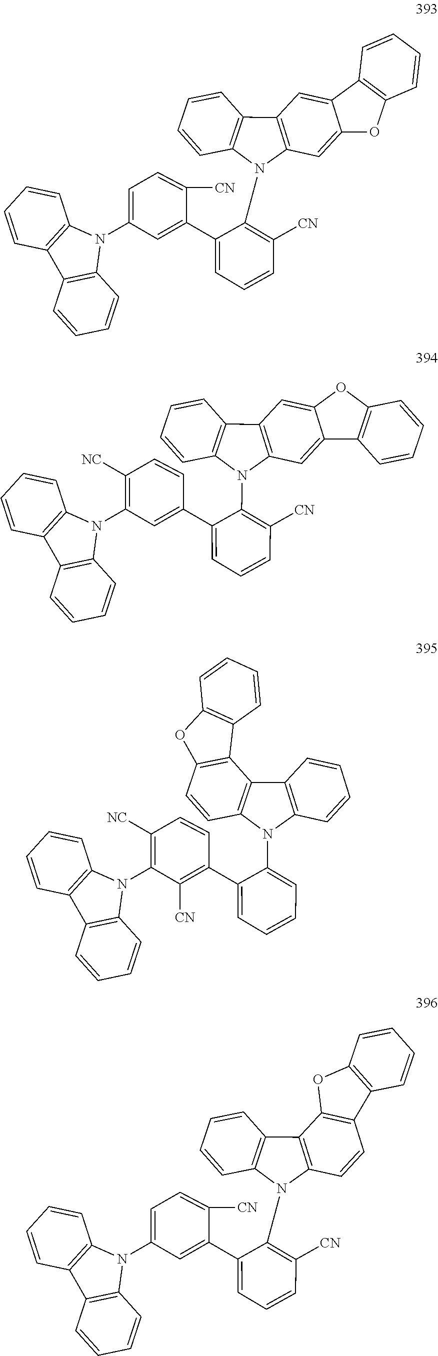 [SMILES: N#Cc1ccc(-n2c3ccccc3c3ccccc32)cc1-c1cccc(C#N)c1-n1c2ccccc2c2cc3c(cc21)oc1ccccc13 ; N#Cc1ccc(-c2cccc(C#N)c2-n2c3ccccc3c3cc4oc5ccccc5c4cc32)cc1-n1c2ccccc2c2ccccc21 ; N#Cc1ccc(-c2ccccc2-n2c3ccccc3c3c4c(ccc32)oc2ccccc24)c(C#N)c1-n1c2ccccc2c2ccccc21 ; N#Cc1ccc(-n2c3ccccc3c3ccccc32)cc1-c1cccc(C#N)c1-n1c2ccccc2c2c3oc4ccccc4c3ccc21]

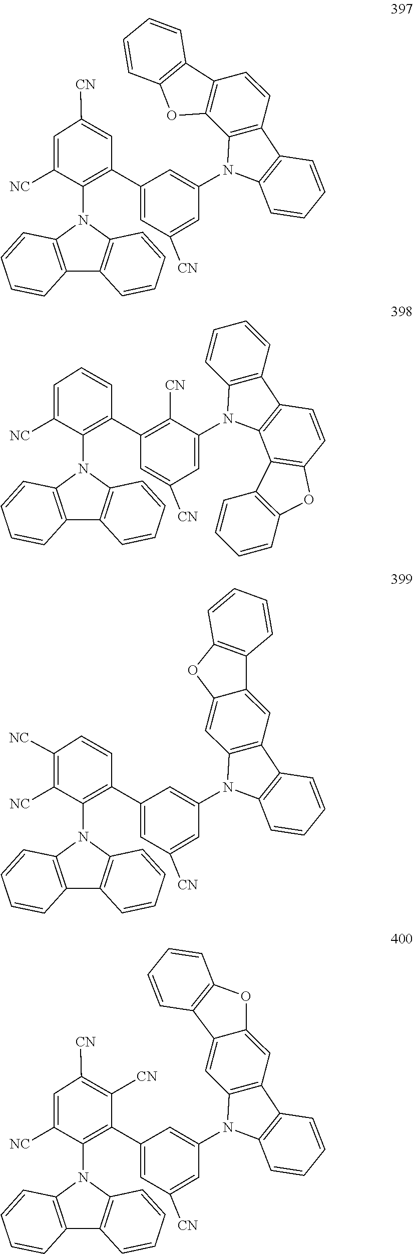

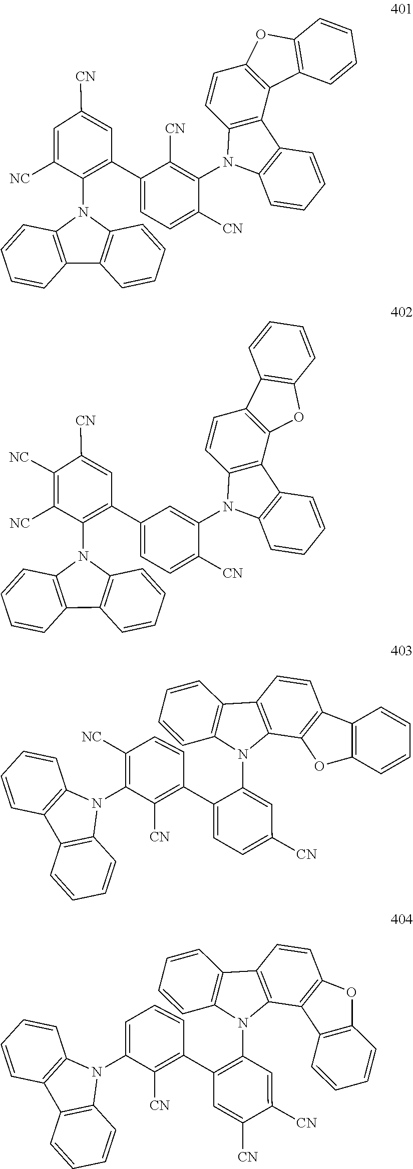 [SMILES: N#Cc1cc(C#N)c(-n2c3ccccc3c3ccccc32)c(-c2ccc(C#N)c(-n3c4ccccc4c4c5c(ccc43)oc3ccccc35)c2C#N)c1 ; N#Cc1ccc(-c2cc(C#N)c(C#N)c(C#N)c2-n2c3ccccc3c3ccccc32)cc1-n1c2ccccc2c2c3oc4ccccc4c3ccc21 ; N#Cc1ccc(-c2ccc(C#N)c(-n3c4ccccc4c4ccccc43)c2C#N)c(-n2c3ccccc3c3ccc4c5ccccc5oc4c32)c1 ; N#Cc1cc(-c2cccc(-n3c4ccccc4c4ccccc43)c2C#N)c(-n2c3ccccc3c3ccc4oc5ccccc5c4c32)cc1C#N]

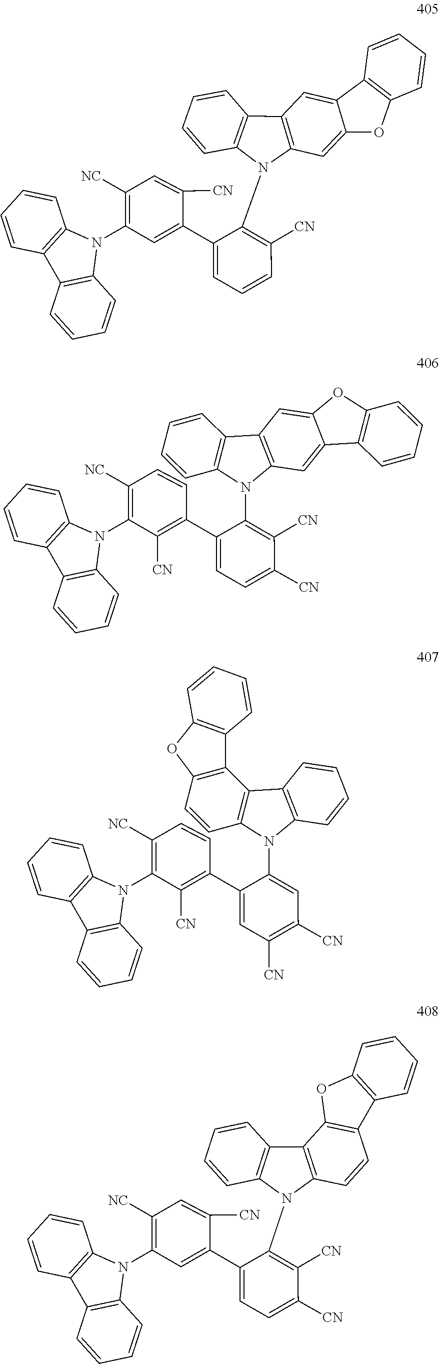 [SMILES: N#Cc1cc(C#N)c(-n2c3ccccc3c3ccccc32)cc1-c1cccc(C#N)c1-n1c2ccccc2c2cc3c(cc21)oc1ccccc13 ; N#Cc1ccc(-c2ccc(C#N)c(-n3c4ccccc4c4ccccc43)c2C#N)c(-n2c3ccccc3c3cc4oc5ccccc5c4cc32)c1C#N ; N#Cc1cc(-c2ccc(C#N)c(-n3c4ccccc4c4ccccc43)c2C#N)c(-n2c3ccccc3c3c4c(ccc32)oc2ccccc24)cc1C#N ; N#Cc1cc(C#N)c(-n2c3ccccc3c3ccccc32)cc1-c1ccc(C#N)c(C#N)c1-n1c2ccccc2c2c3oc4ccccc4c3ccc21]

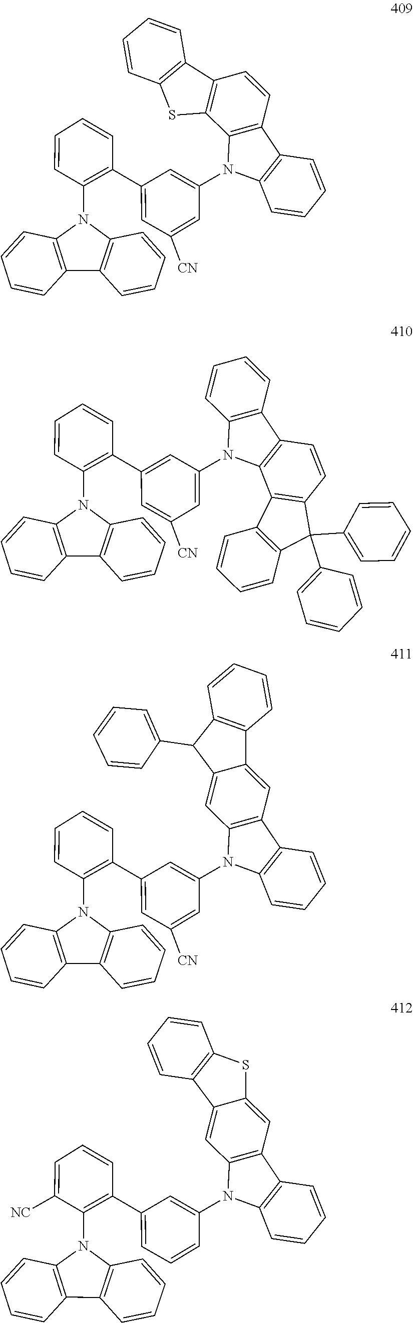

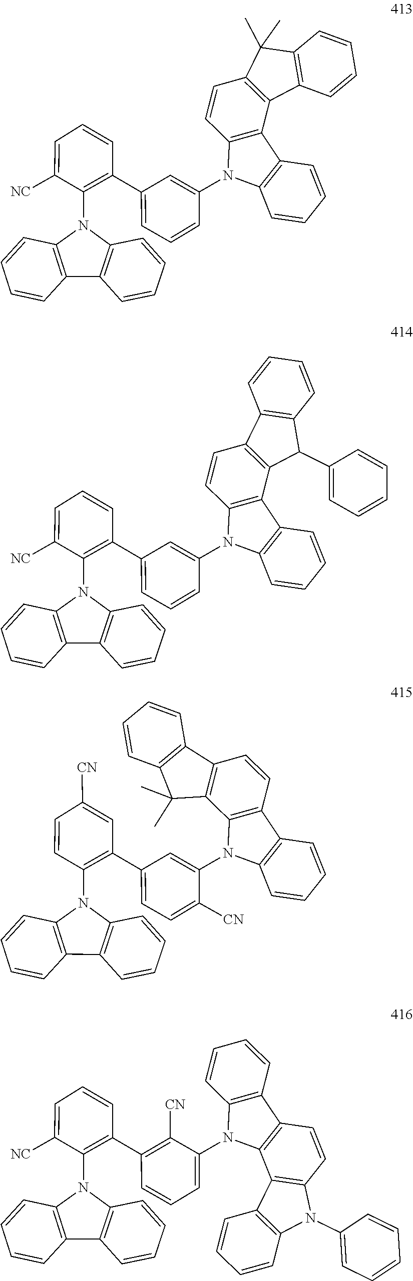

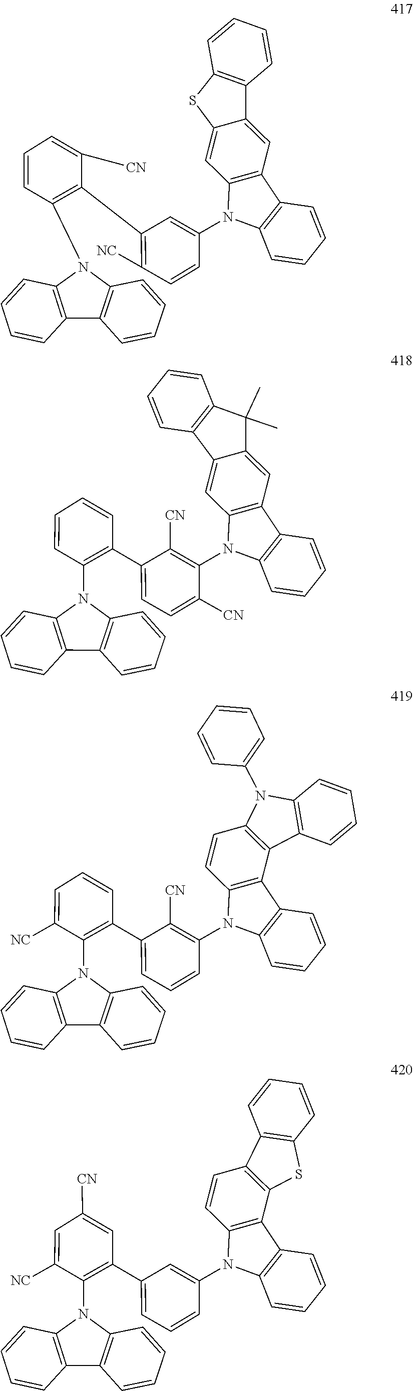

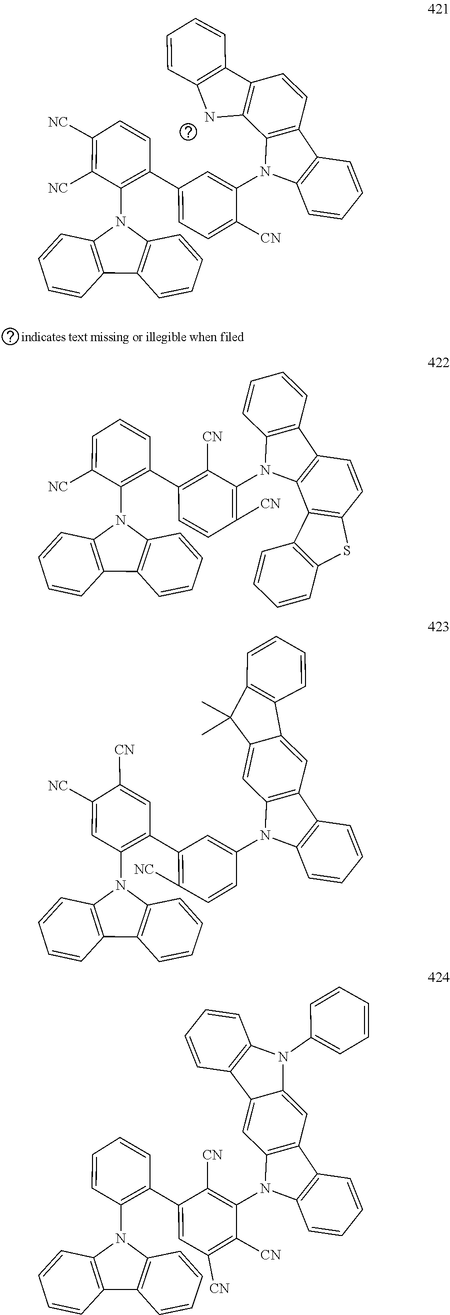

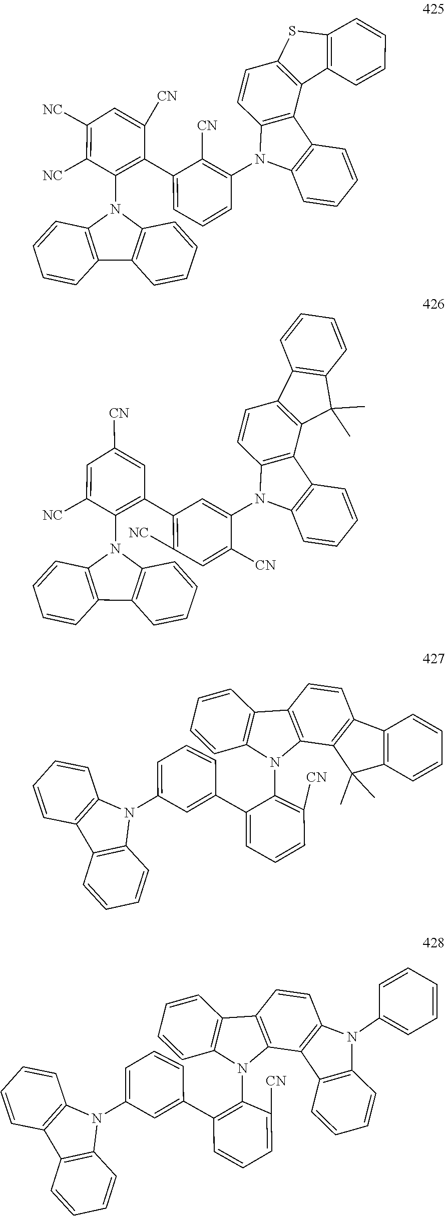 [SMILES: N#Cc1cc(C#N)c(-c2cccc(-n3c4ccccc4c4c5c(ccc43)sc3ccccc35)c2C#N)c(-n2c3ccccc3c3ccccc32)c1C#N ; CC1(C)c2ccccc2-c2ccc3c(c21)c1ccccc1n3-c1cc(-c2cc(C#N)cc(C#N)c2-n2c3ccccc3c3ccccc32)c(C#N)cc1C#N ; CC1(C)c2ccccc2-c2ccc3c4ccccc4n(-c4c(C#N)cccc4-c4cccc(-n5c6ccccc6c6ccccc65)c4)c3c21 ; N#Cc1cccc(-c2cccc(-n3c4ccccc4c4ccccc43)c2)c1-n1c2ccccc2c2ccc3c(c4ccccc4n3-c3ccccc3)c21]

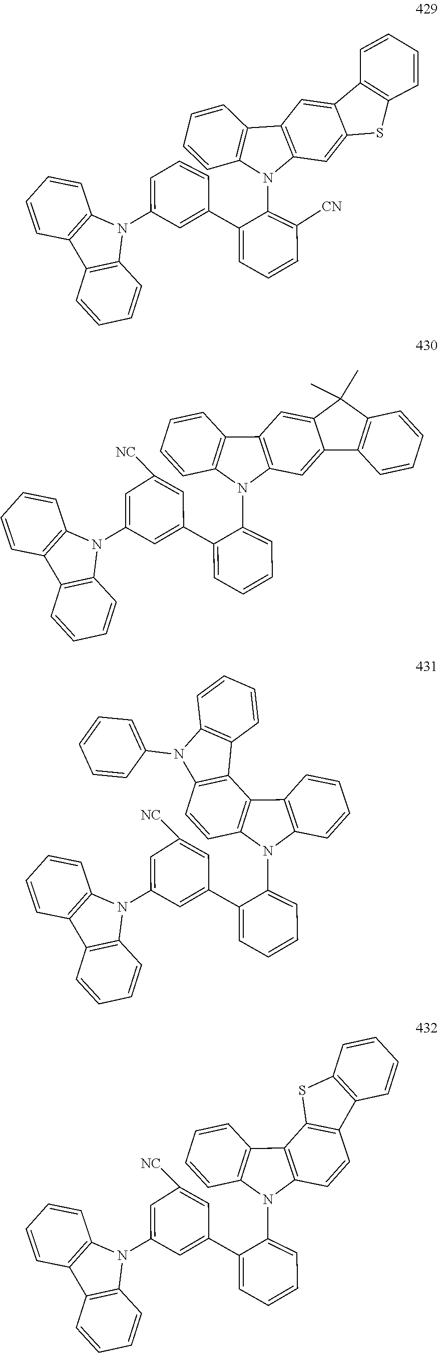 [SMILES: N#Cc1cccc(-c2cccc(-n3c4ccccc4c4ccccc43)c2)c1-n1c2ccccc2c2cc3c(cc21)sc1ccccc13 ; CC1(C)c2ccccc2-c2cc3c(cc21)c1ccccc1n3-c1ccccc1-c1cc(C#N)cc(-n2c3ccccc3c3ccccc32)c1 ; N#Cc1cc(-c2ccccc2-n2c3ccccc3c3c4c5ccccc5n(-c5ccccc5)c4ccc32)cc(-n2c3ccccc3c3ccccc32)c1 ; N#Cc1cc(-c2ccccc2-n2c3ccccc3c3c4sc5ccccc5c4ccc32)cc(-n2c3ccccc3c3ccccc32)c1]

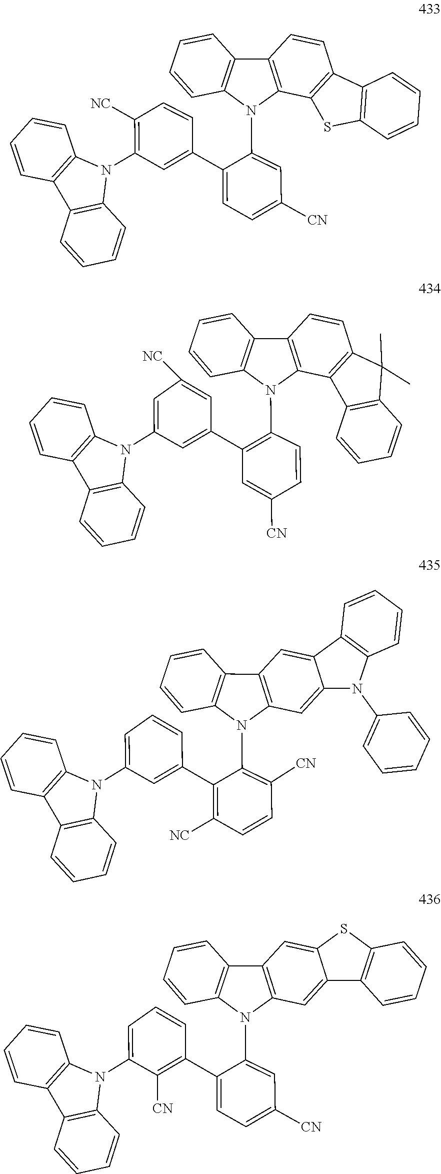 [SMILES: N#Cc1ccc(-c2ccc(C#N)c(-n3c4ccccc4c4ccccc43)c2)c(-n2c3ccccc3c3ccc4c5ccccc5sc4c32)c1 ; CC1(C)c2ccccc2-c2c1ccc1c3ccccc3n(-c3ccc(C#N)cc3-c3cc(C#N)cc(-n4c5ccccc5c5ccccc54)c3)c21 ; N#Cc1ccc(C#N)c(-n2c3ccccc3c3cc4c5ccccc5n(-c5ccccc5)c4cc32)c1-c1cccc(-n2c3ccccc3c3ccccc32)c1 ; N#Cc1ccc(-c2cccc(-n3c4ccccc4c4ccccc43)c2C#N)c(-n2c3ccccc3c3cc4sc5ccccc5c4cc32)c1]

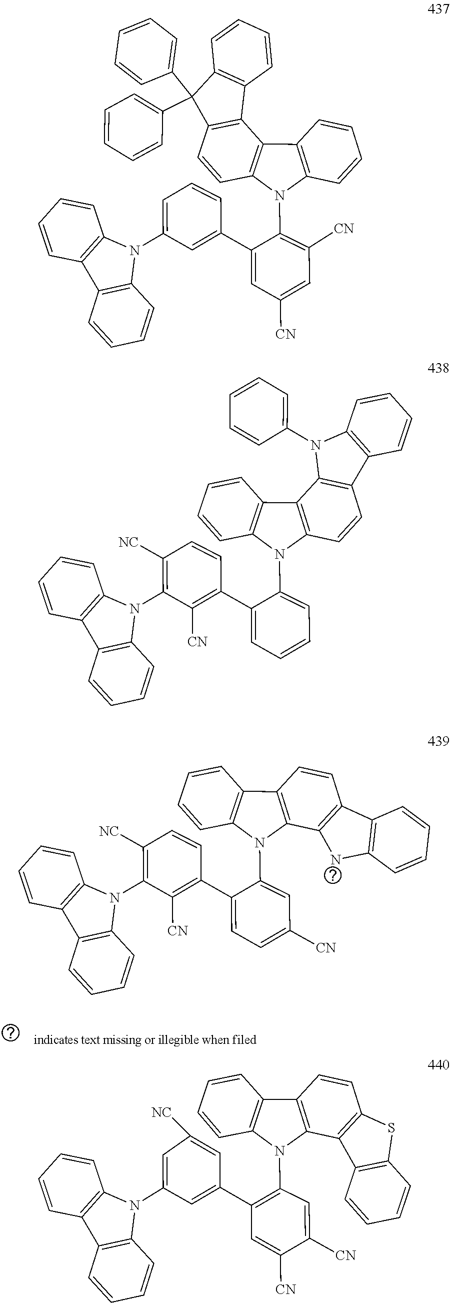 [SMILES: N#Cc1cc(C#N)c(-n2c3ccccc3c3c4c(ccc32)C(c2ccccc2)(c2ccccc2)c2ccccc2-4)c(-c2cccc(-n3c4ccccc4c4ccccc43)c2)c1 ; N#Cc1ccc(-c2ccccc2-n2c3ccccc3c3c2ccc2c4ccccc4n(-c4ccccc4)c23)c(C#N)c1-n1c2ccccc2c2ccccc21 ; N#Cc1ccc(-c2ccc(C#N)c(-n3c4ccccc4c4ccccc43)c2C#N)c(-n2c3ccccc3c3ccc4c5ccccc5[nH]c4c32)c1 ; N#Cc1cc(-c2cc(C#N)c(C#N)cc2-n2c3ccccc3c3ccc4sc5ccccc5c4c32)cc(-n2c3ccccc3c3ccccc32)c1]

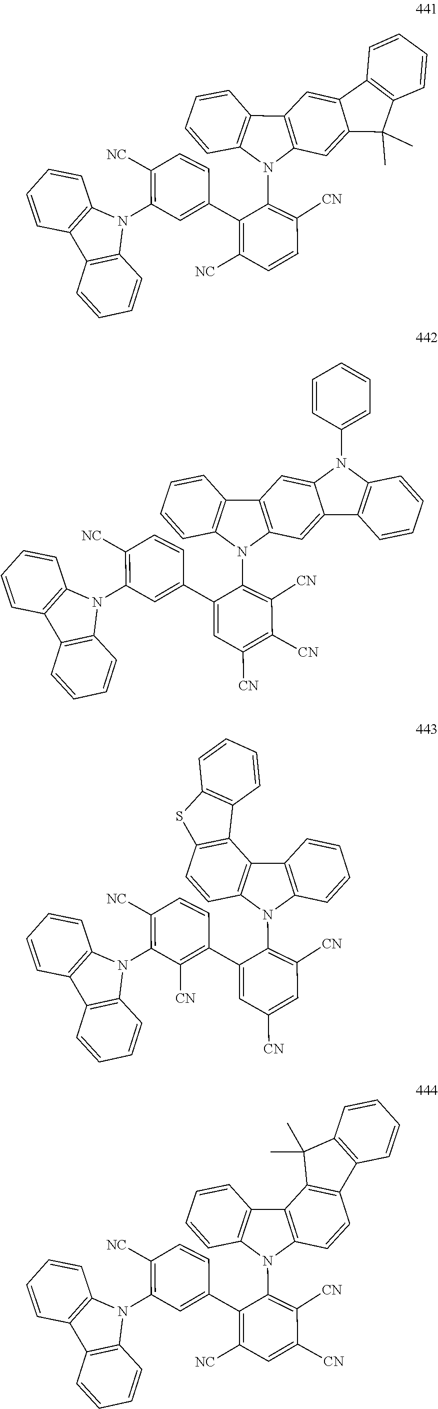 [SMILES: CC1(C)c2ccccc2-c2cc3c4ccccc4n(-c4c(C#N)ccc(C#N)c4-c4ccc(C#N)c(-n5c6ccccc6c6ccccc65)c4)c3cc21 ; N#Cc1ccc(-c2cc(C#N)c(C#N)c(C#N)c2-n2c3ccccc3c3cc4c(cc32)c2ccccc2n4-c2ccccc2)cc1-n1c2ccccc2c2ccccc21 ; N#Cc1cc(C#N)c(-n2c3ccccc3c3c4c(ccc32)sc2ccccc24)c(-c2ccc(C#N)c(-n3c4ccccc4c4ccccc43)c2C#N)c1 ; CC1(C)c2ccccc2-c2ccc3c(c21)c1ccccc1n3-c1c(C#N)c(C#N)cc(C#N)c1-c1ccc(C#N)c(-n2c3ccccc3c3ccccc32)c1]

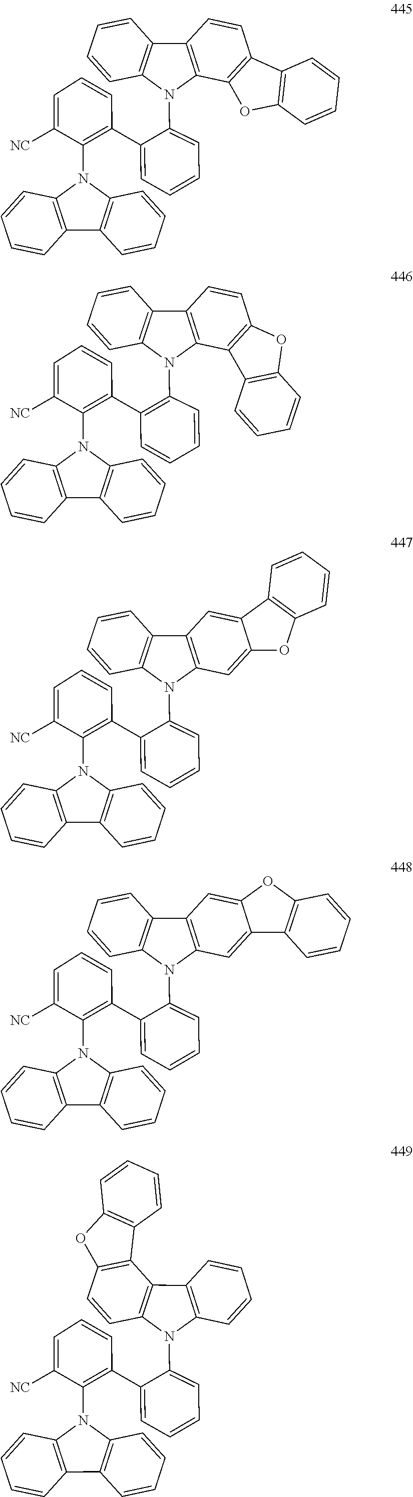

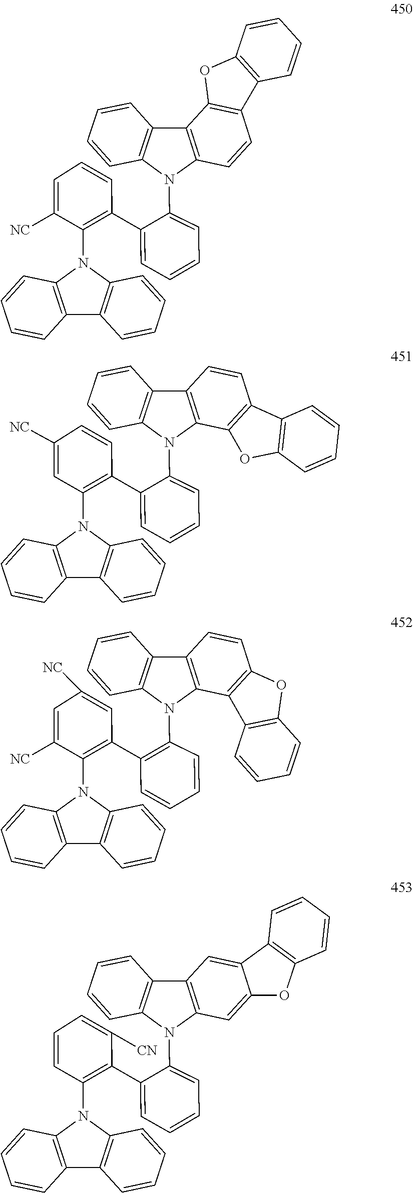

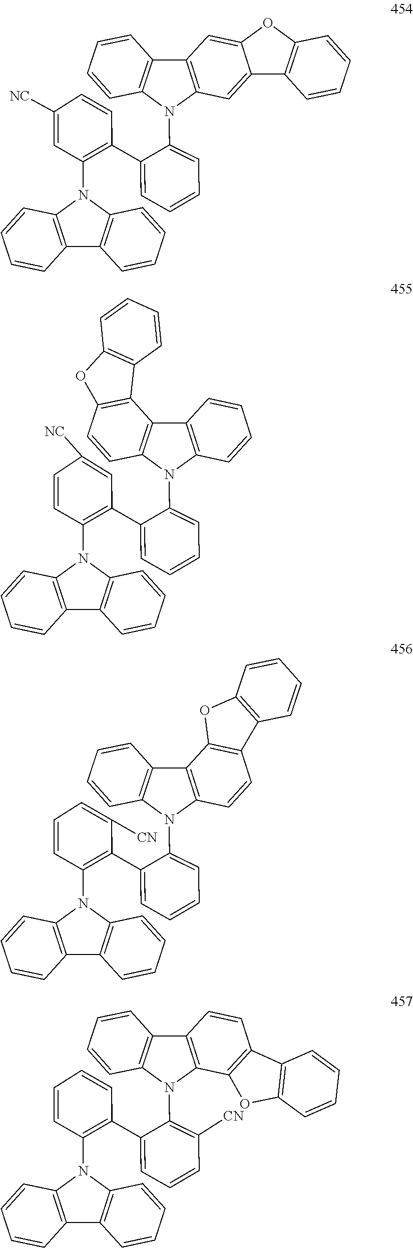

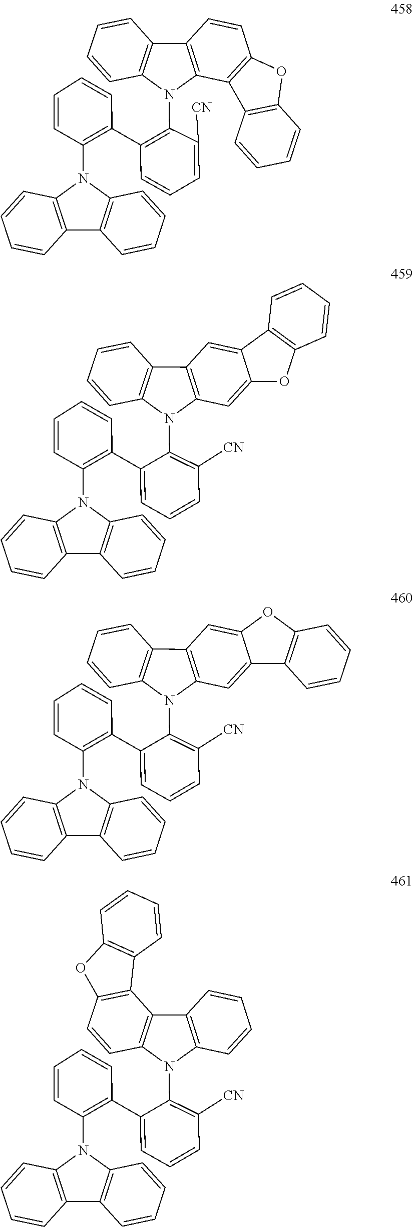

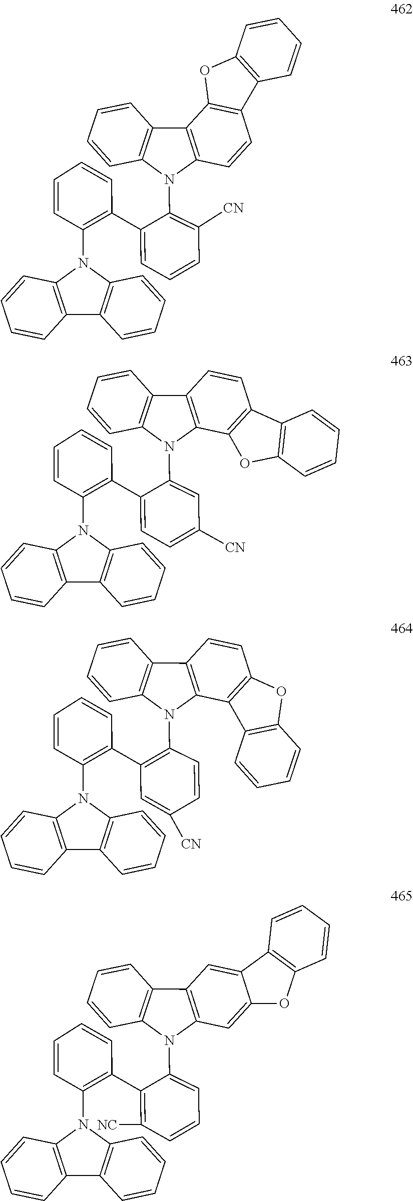

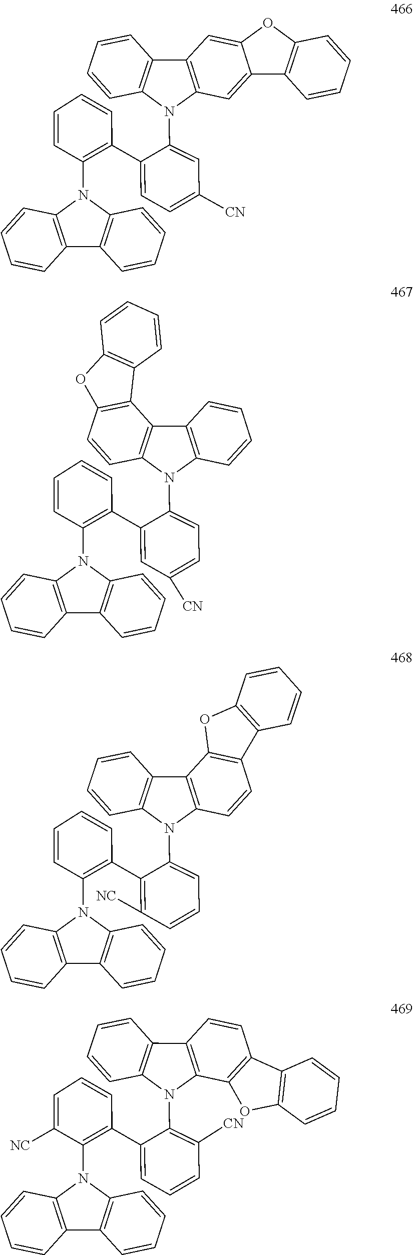

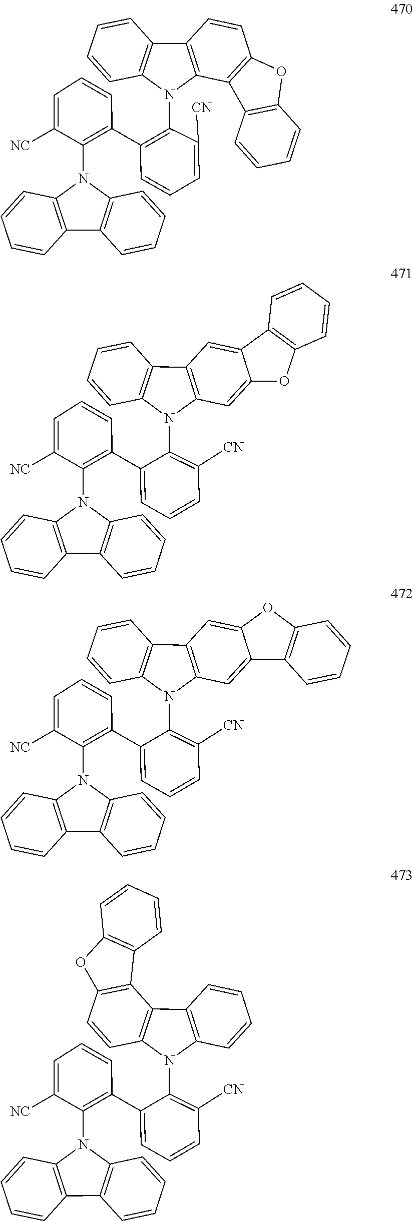

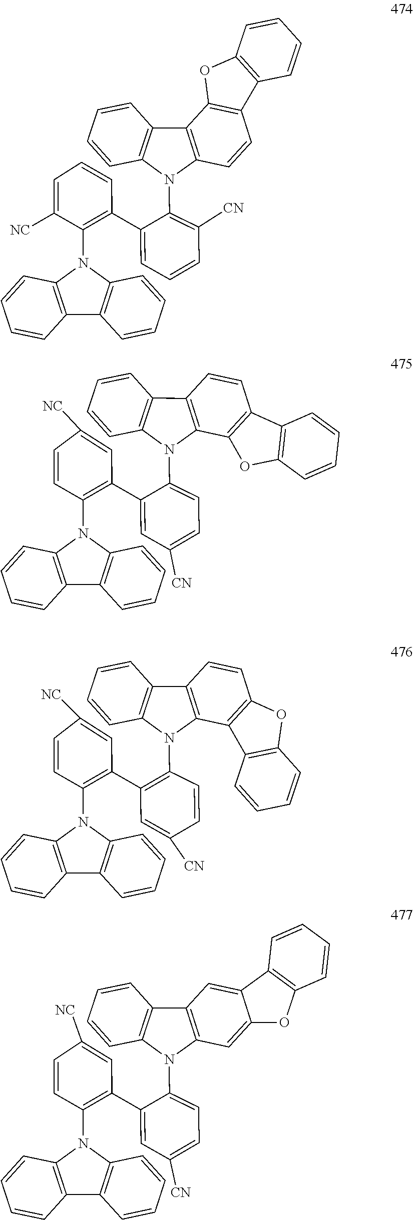

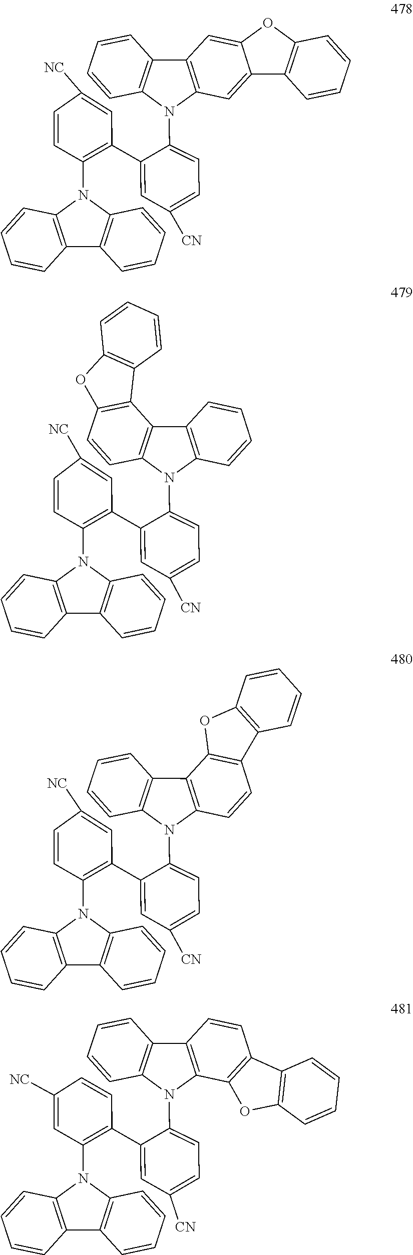

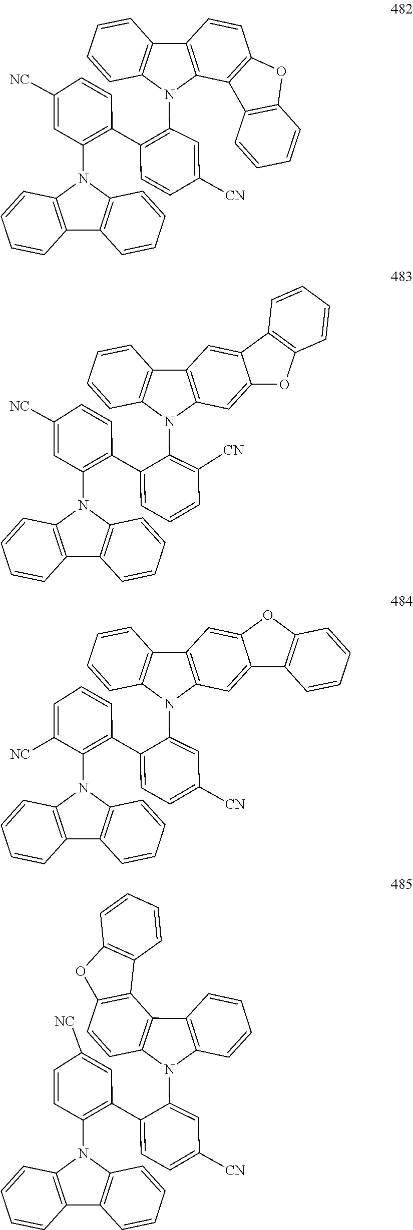

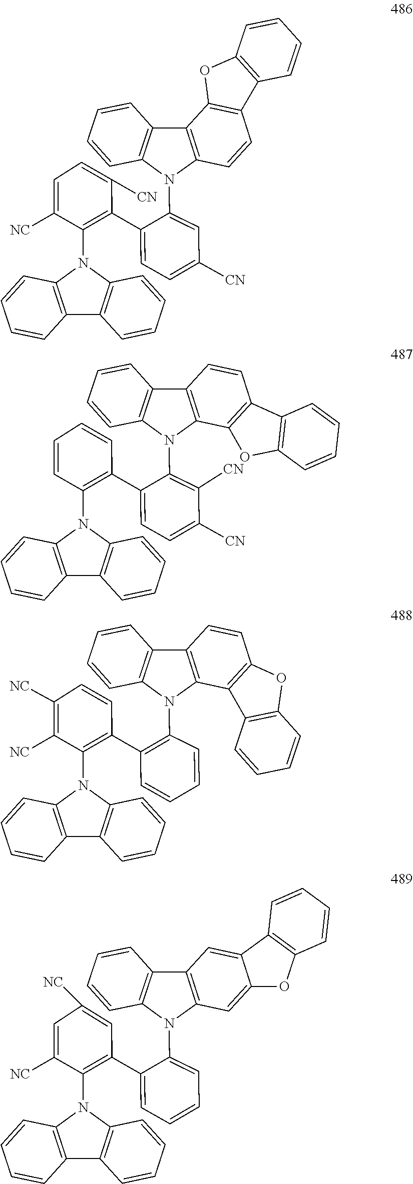

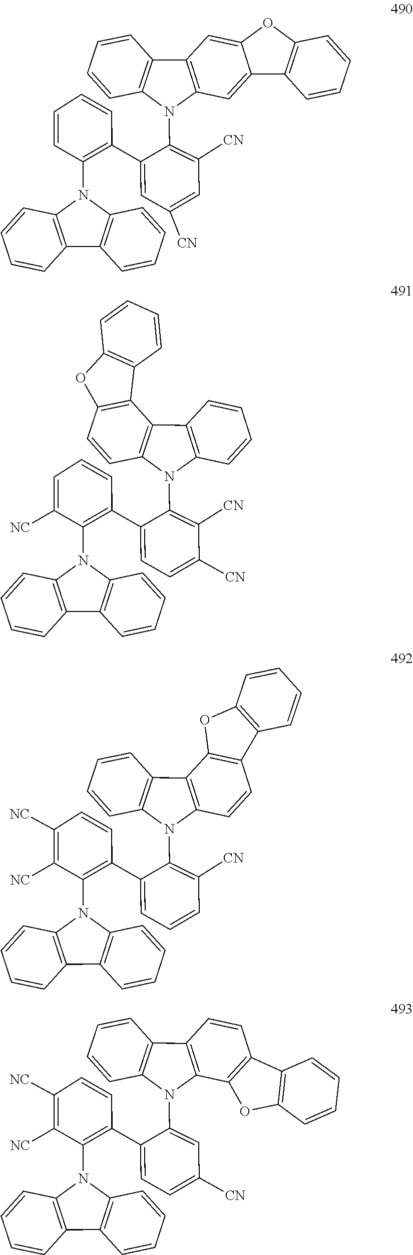

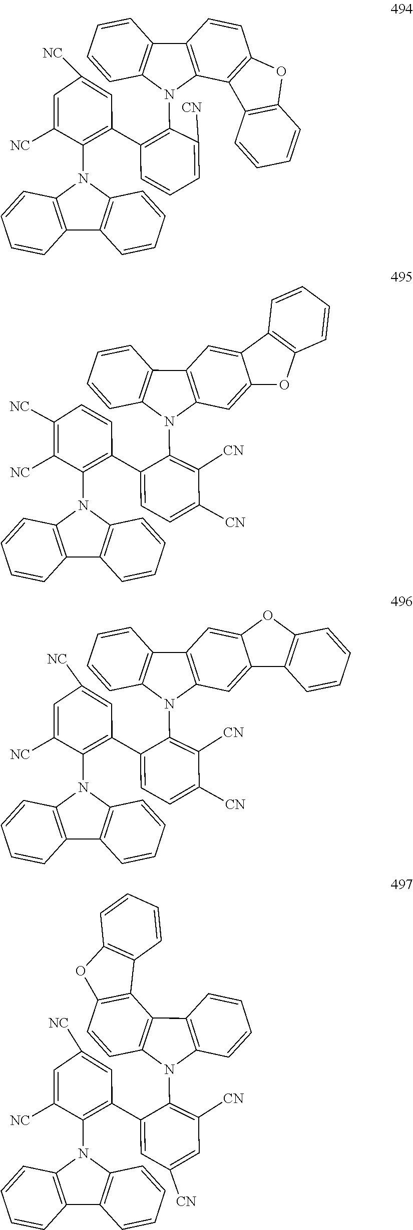

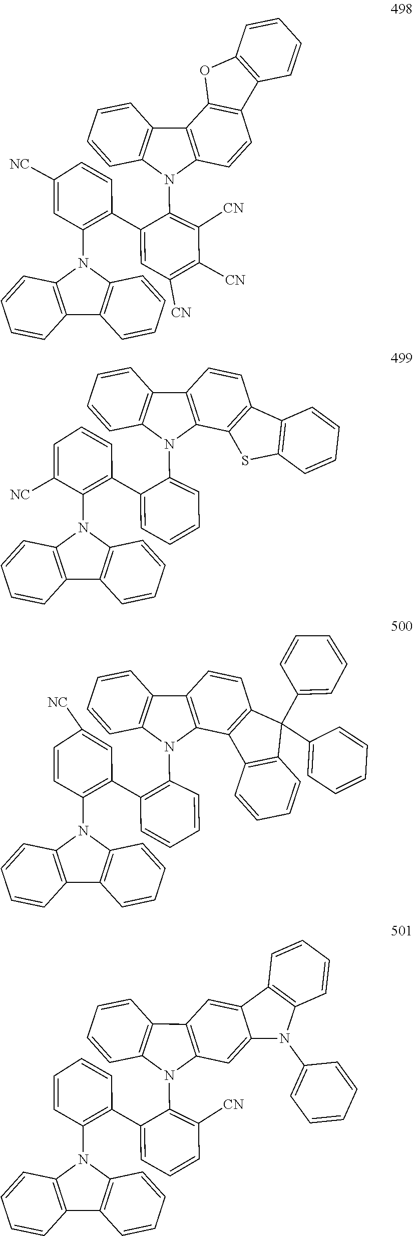

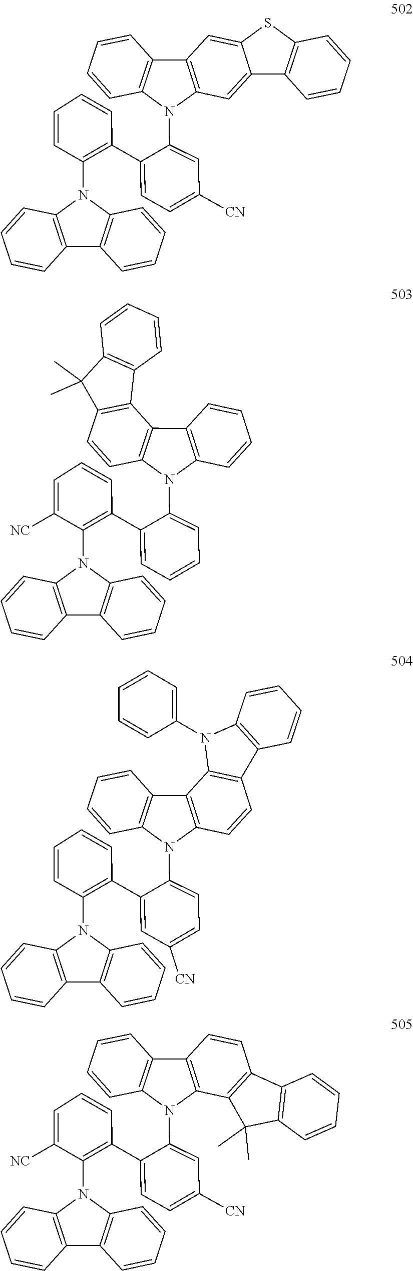

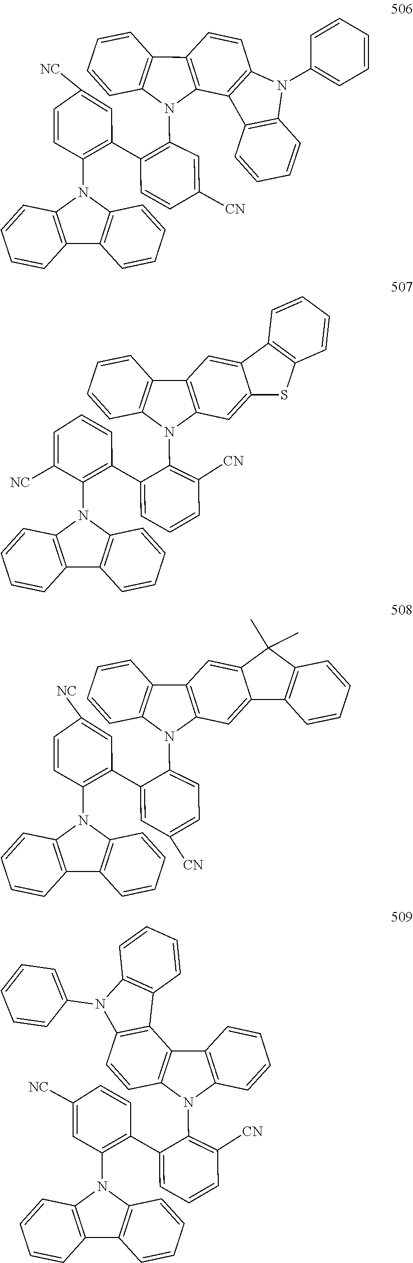

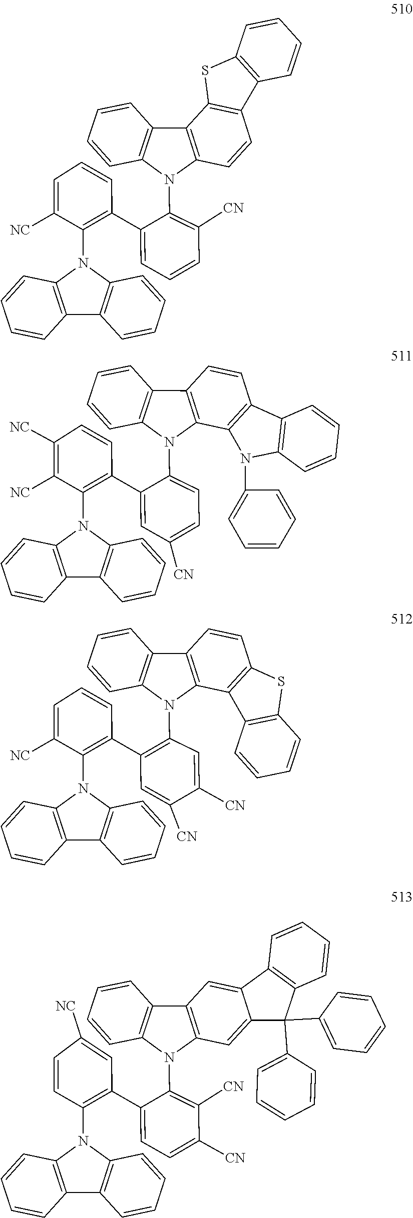

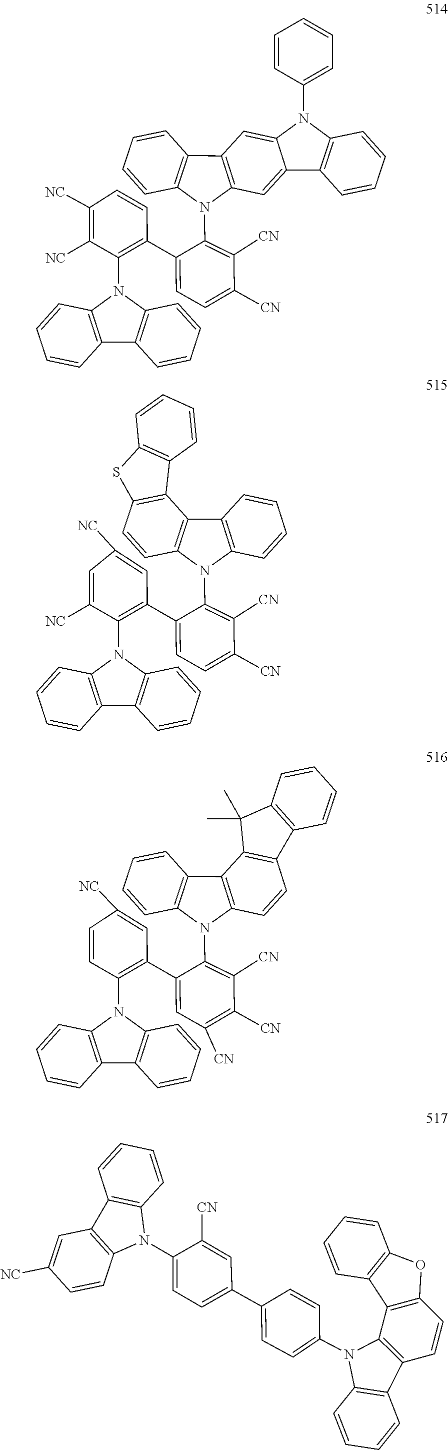

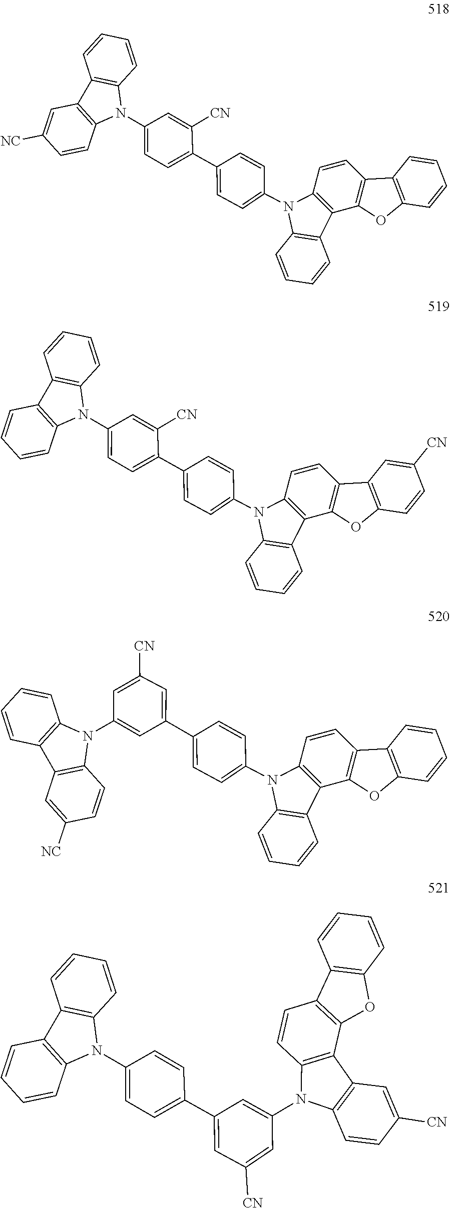 [SMILES: N#Cc1ccc2c(c1)c1ccccc1n2-c1ccc(-c2ccc(-n3c4ccccc4c4c5oc6ccccc6c5ccc43)cc2)c(C#N)c1 ; N#Cc1ccc2oc3c(ccc4c3c3ccccc3n4-c3ccc(-c4ccc(-n5c6ccccc6c6ccccc65)cc4C#N)cc3)c2c1 ; N#Cc1cc(-c2ccc(-n3c4ccccc4c4c5oc6ccccc6c5ccc43)cc2)cc(-n2c3ccccc3c3cc(C#N)ccc32)c1 ; N#Cc1cc(-c2ccc(-n3c4ccccc4c4ccccc43)cc2)cc(-n2c3ccc(C#N)cc3c3c4oc5ccccc5c4ccc32)c1]

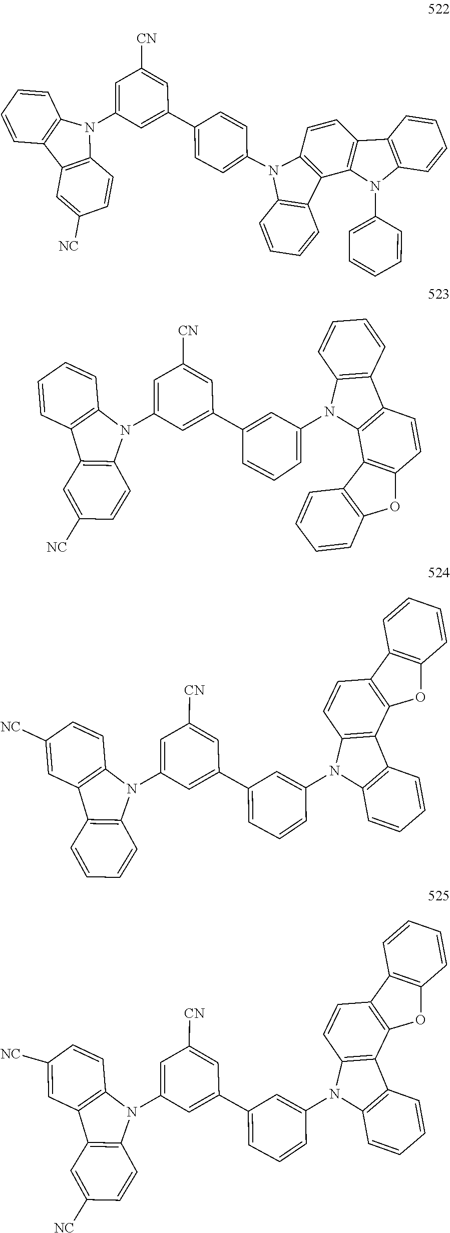

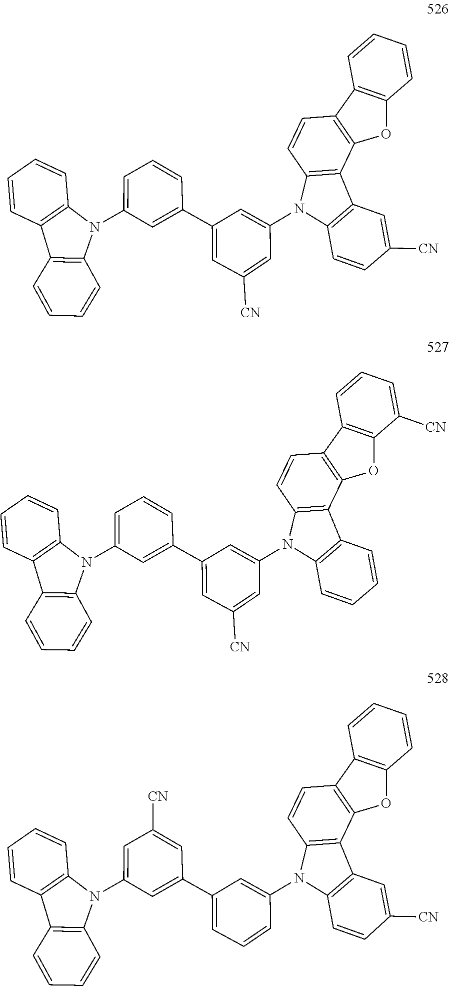 [SMILES: N#Cc1cc(-c2cccc(-n3c4ccccc4c4ccccc43)c2)cc(-n2c3ccc(C#N)cc3c3c4oc5ccccc5c4ccc32)c1 ; N#Cc1cc(-c2cccc(-n3c4ccccc4c4ccccc43)c2)cc(-n2c3ccccc3c3c4oc5c(C#N)cccc5c4ccc32)c1 ; N#Cc1cc(-c2cccc(-n3c4ccc(C#N)cc4c4c5oc6ccccc6c5ccc43)c2)cc(-n2c3ccccc3c3ccccc32)c1]

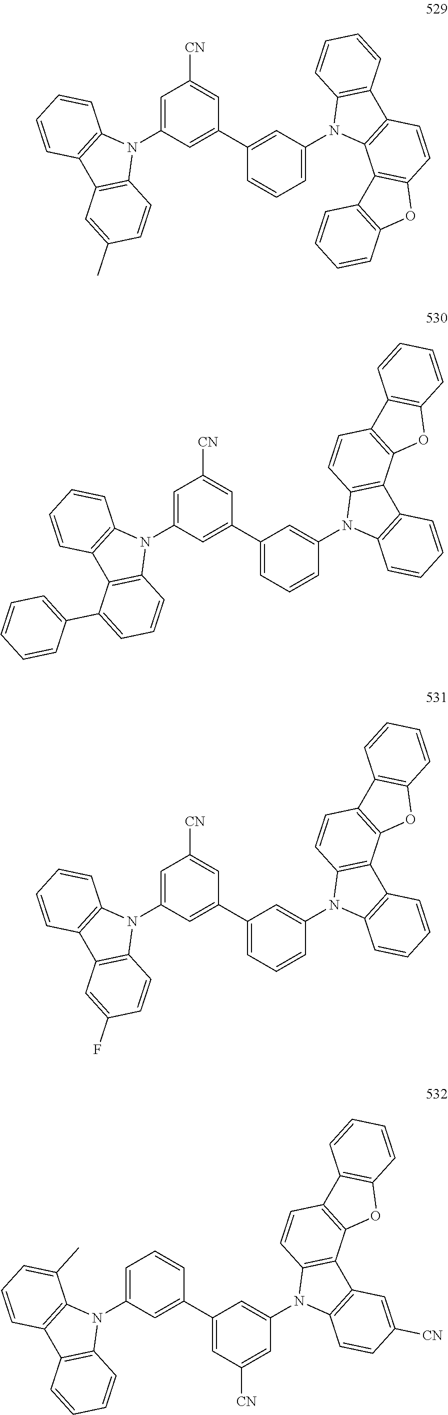 [SMILES: Cc1ccc2c(c1)c1ccccc1n2-c1cc(C#N)cc(-c2cccc(-n3c4ccccc4c4ccc5oc6ccccc6c5c43)c2)c1 ; N#Cc1cc(-c2cccc(-n3c4ccccc4c4c5oc6ccccc6c5ccc43)c2)cc(-n2c3ccccc3c3c(-c4ccccc4)cccc32)c1 ; N#Cc1cc(-c2cccc(-n3c4ccccc4c4c5oc6ccccc6c5ccc43)c2)cc(-n2c3ccccc3c3cc(F)ccc32)c1 ; Cc1cccc2c3ccccc3n(-c3cccc(-c4cc(C#N)cc(-n5c6ccc(C#N)cc6c6c7oc8ccccc8c7ccc65)c4)c3)c12]

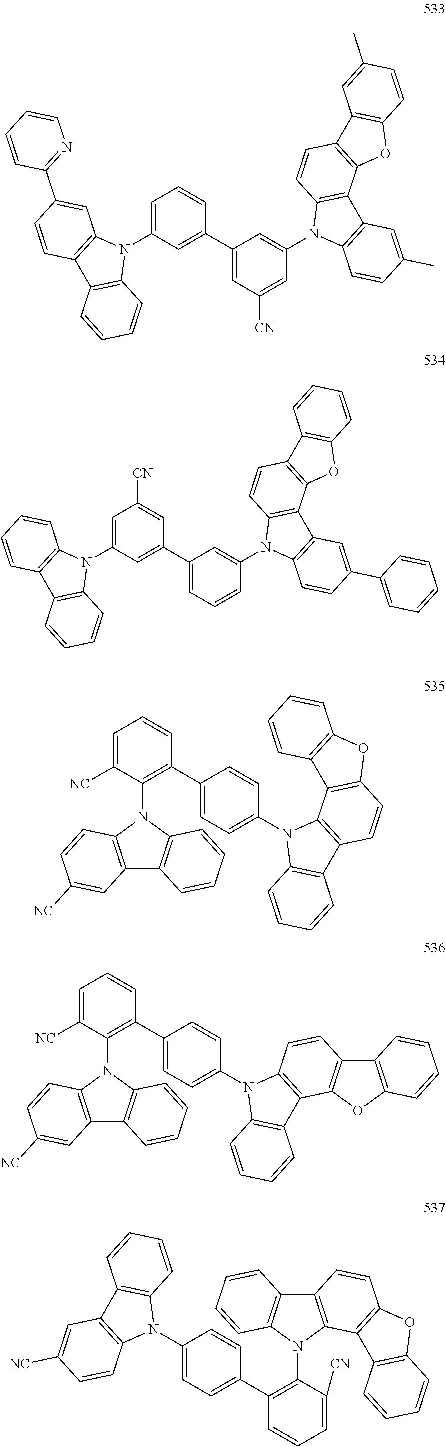 [SMILES: Cc1ccc2oc3c(ccc4c3c3cc(C)ccc3n4-c3cc(C#N)cc(-c4cccc(-n5c6ccccc6c6ccc(-c7ccccn7)cc65)c4)c3)c2c1 ; N#Cc1cc(-c2cccc(-n3c4ccc(-c5ccccc5)cc4c4c5oc6ccccc6c5ccc43)c2)cc(-n2c3ccccc3c3ccccc32)c1 ; N#Cc1ccc2c(c1)c1ccccc1n2-c1c(C#N)cccc1-c1ccc(-n2c3ccccc3c3ccc4oc5ccccc5c4c32)cc1 ; N#Cc1ccc2c(c1)c1ccccc1n2-c1c(C#N)cccc1-c1ccc(-n2c3ccccc3c3c4oc5ccccc5c4ccc32)cc1 ; N#Cc1ccc2c(c1)c1ccccc1n2-c1ccc(-c2cccc(C#N)c2-n2c3ccccc3c3ccc4oc5ccccc5c4c32)cc1]

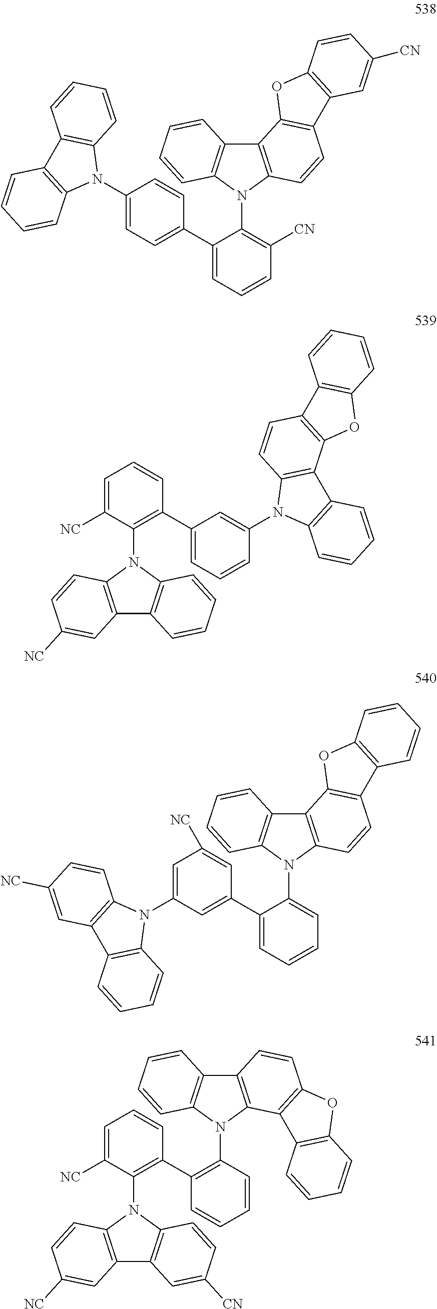 [SMILES: N#Cc1ccc2oc3c(ccc4c3c3ccccc3n4-c3c(C#N)cccc3-c3ccc(-n4c5ccccc5c5ccccc54)cc3)c2c1 ; N#Cc1ccc2c(c1)c1ccccc1n2-c1c(C#N)cccc1-c1cccc(-n2c3ccccc3c3c4oc5ccccc5c4ccc32)c1 ; N#Cc1cc(-c2ccccc2-n2c3ccccc3c3c4oc5ccccc5c4ccc32)cc(-n2c3ccccc3c3cc(C#N)ccc32)c1 ; N#Cc1ccc2c(c1)c1cc(C#N)ccc1n2-c1c(C#N)cccc1-c1ccccc1-n1c2ccccc2c2ccc3oc4ccccc4c3c21]

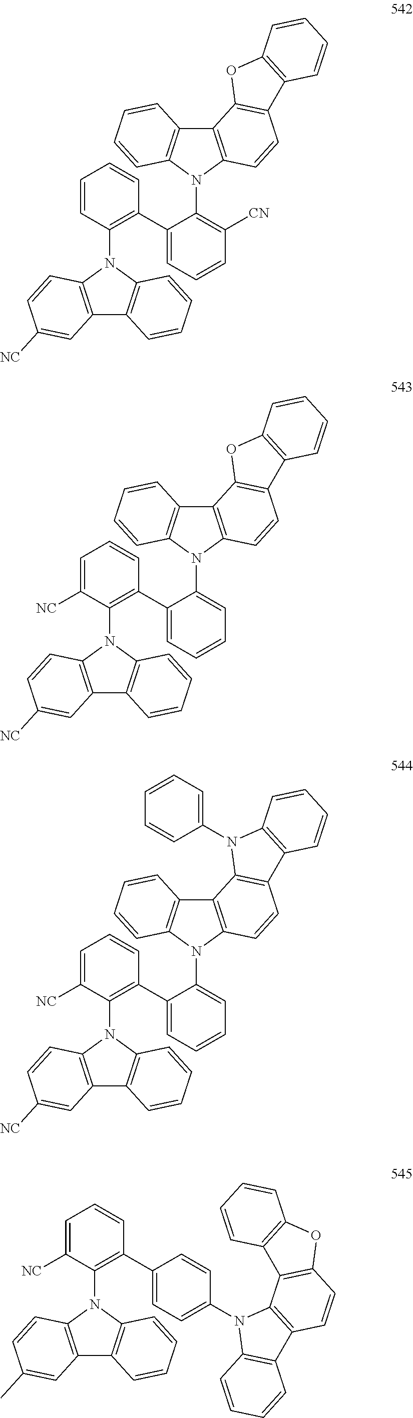 [SMILES: N#Cc1ccc2c(c1)c1ccccc1n2-c1ccccc1-c1cccc(C#N)c1-n1c2ccccc2c2c3oc4ccccc4c3ccc21 ; N#Cc1ccc2c(c1)c1ccccc1n2-c1c(C#N)cccc1-c1ccccc1-n1c2ccccc2c2c3oc4ccccc4c3ccc21 ; N#Cc1ccc2c(c1)c1ccccc1n2-c1c(C#N)cccc1-c1ccccc1-n1c2ccccc2c2c1ccc1c3ccccc3n(-c3ccccc3)c12 ; Cc1ccc2c(c1)c1ccccc1n2-c1c(C#N)cccc1-c1ccc(-n2c3ccccc3c3ccc4oc5ccccc5c4c32)cc1]

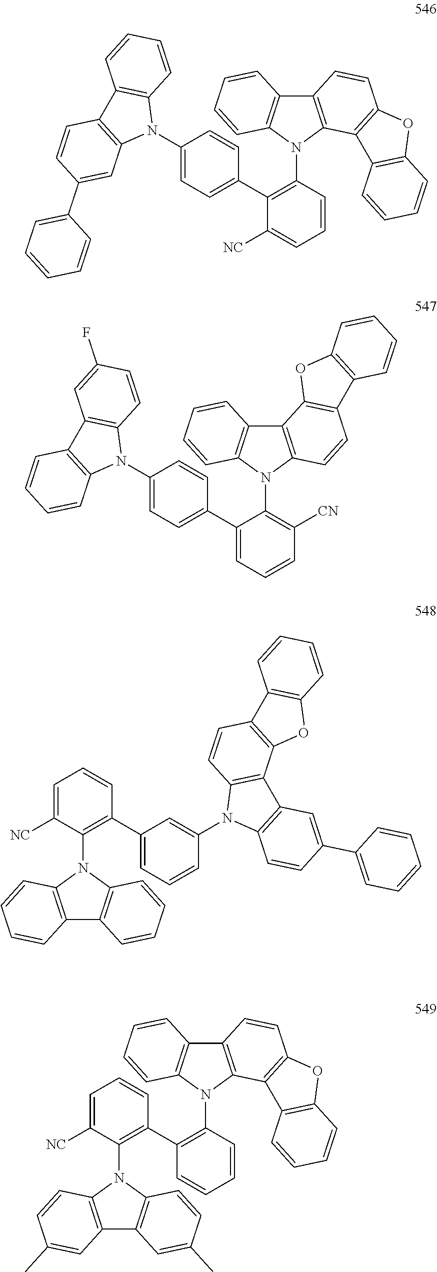 [SMILES: N#Cc1cccc(-n2c3ccccc3c3ccc4oc5ccccc5c4c32)c1-c1ccc(-n2c3ccccc3c3ccc(-c4ccccc4)cc32)cc1 ; N#Cc1cccc(-c2ccc(-n3c4ccccc4c4cc(F)ccc43)cc2)c1-n1c2ccccc2c2c3oc4ccccc4c3ccc21 ; N#Cc1cccc(-c2cccc(-n3c4ccc(-c5ccccc5)cc4c4c5oc6ccccc6c5ccc43)c2)c1-n1c2ccccc2c2ccccc21 ; Cc1ccc2c(c1)c1cc(C)ccc1n2-c1c(C#N)cccc1-c1ccccc1-n1c2ccccc2c2ccc3oc4ccccc4c3c21]

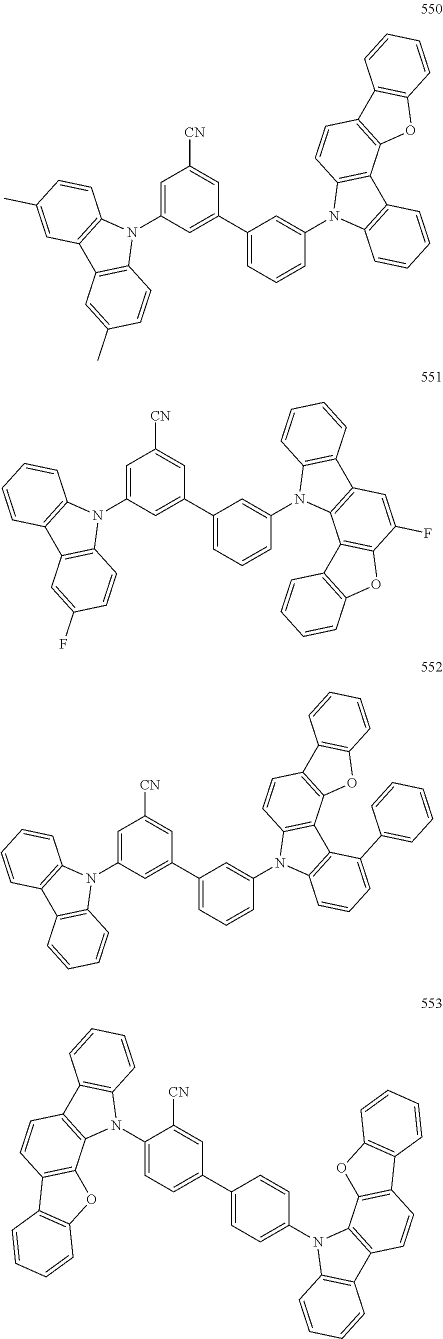 [SMILES: Cc1ccc2c(c1)c1cc(C)ccc1n2-c1cc(C#N)cc(-c2cccc(-n3c4ccccc4c4c5oc6ccccc6c5ccc43)c2)c1 ; N#Cc1cc(-c2cccc(-n3c4ccccc4c4cc(F)c5oc6ccccc6c5c43)c2)cc(-n2c3ccccc3c3cc(F)ccc32)c1 ; N#Cc1cc(-c2cccc(-n3c4cccc(-c5ccccc5)c4c4c5oc6ccccc6c5ccc43)c2)cc(-n2c3ccccc3c3ccccc32)c1 ; N#Cc1cc(-c2ccc(-n3c4ccccc4c4ccc5c6ccccc6oc5c43)cc2)ccc1-n1c2ccccc2c2ccc3c4ccccc4oc3c21]

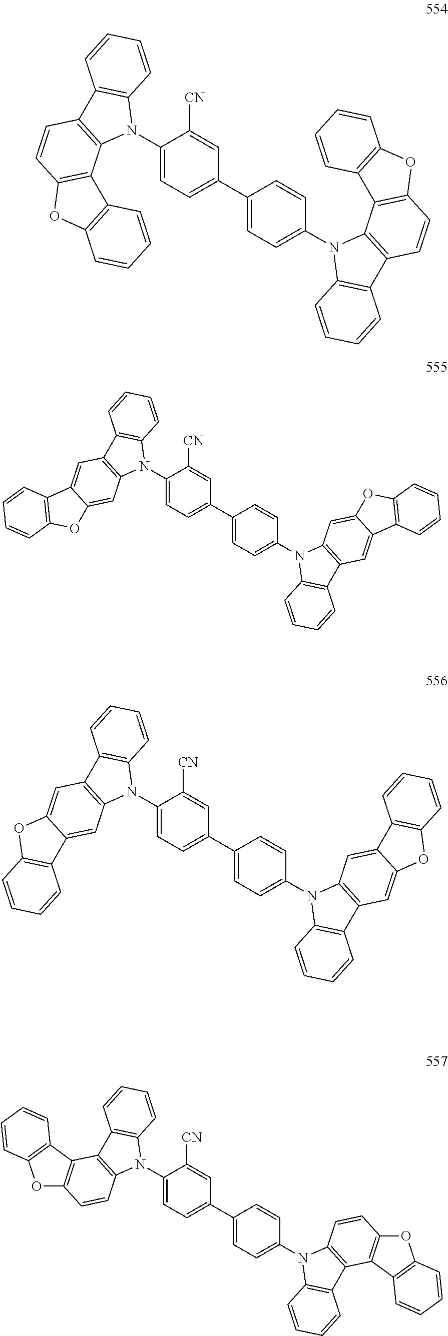 [SMILES: N#Cc1cc(-c2ccc(-n3c4ccccc4c4ccc5oc6ccccc6c5c43)cc2)ccc1-n1c2ccccc2c2ccc3oc4ccccc4c3c21 ; N#Cc1cc(-c2ccc(-n3c4ccccc4c4cc5c(cc43)oc3ccccc35)cc2)ccc1-n1c2ccccc2c2cc3c(cc21)oc1ccccc13 ; N#Cc1cc(-c2ccc(-n3c4ccccc4c4cc5oc6ccccc6c5cc43)cc2)ccc1-n1c2ccccc2c2cc3oc4ccccc4c3cc21 ; N#Cc1cc(-c2ccc(-n3c4ccccc4c4c5c(ccc43)oc3ccccc35)cc2)ccc1-n1c2ccccc2c2c3c(ccc21)oc1ccccc13]

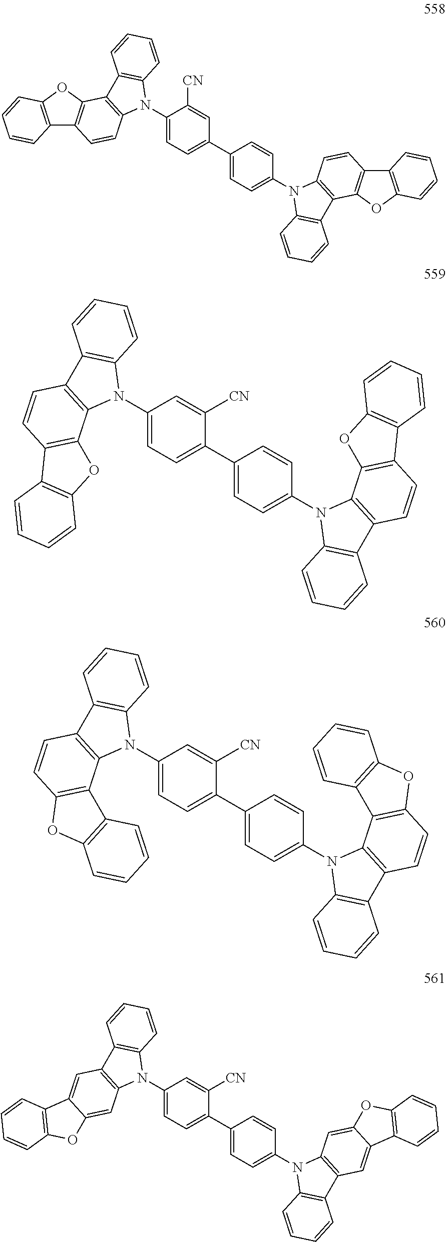 [SMILES: N#Cc1cc(-c2ccc(-n3c4ccccc4c4c5oc6ccccc6c5ccc43)cc2)ccc1-n1c2ccccc2c2c3oc4ccccc4c3ccc21 ; N#Cc1cc(-n2c3ccccc3c3ccc4c5ccccc5oc4c32)ccc1-c1ccc(-n2c3ccccc3c3ccc4c5ccccc5oc4c32)cc1 ; N#Cc1cc(-n2c3ccccc3c3ccc4oc5ccccc5c4c32)ccc1-c1ccc(-n2c3ccccc3c3ccc4oc5ccccc5c4c32)cc1 ; N#Cc1cc(-n2c3ccccc3c3cc4c(cc32)oc2ccccc24)ccc1-c1ccc(-n2c3ccccc3c3cc4c(cc32)oc2ccccc24)cc1]

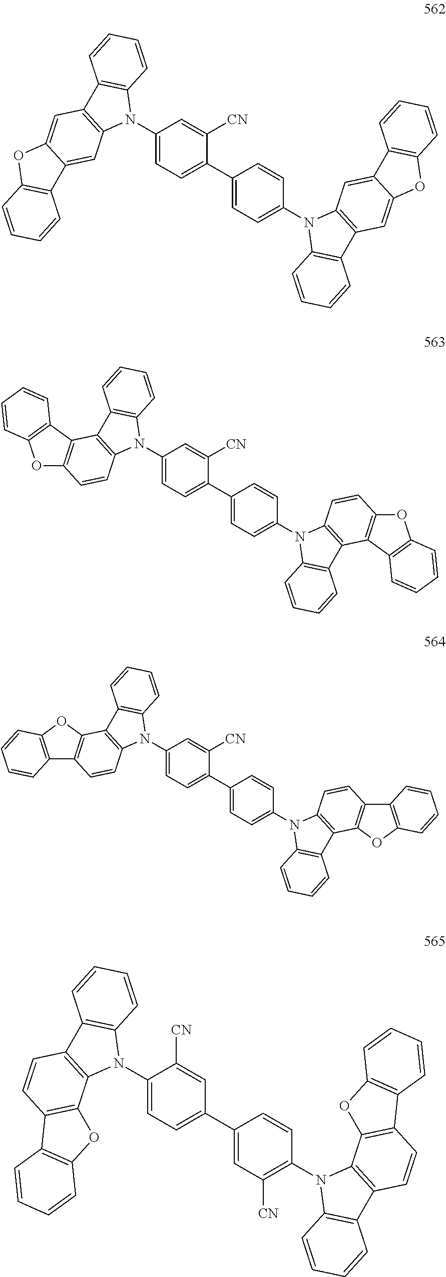 [SMILES: N#Cc1cc(-n2c3ccccc3c3cc4oc5ccccc5c4cc32)ccc1-c1ccc(-n2c3ccccc3c3cc4oc5ccccc5c4cc32)cc1 ; N#Cc1cc(-n2c3ccccc3c3c4c(ccc32)oc2ccccc24)ccc1-c1ccc(-n2c3ccccc3c3c4c(ccc32)oc2ccccc24)cc1 ; N#Cc1cc(-n2c3ccccc3c3c4oc5ccccc5c4ccc32)ccc1-c1ccc(-n2c3ccccc3c3c4oc5ccccc5c4ccc32)cc1 ; N#Cc1cc(-c2ccc(-n3c4ccccc4c4ccc5c6ccccc6oc5c43)c(C#N)c2)ccc1-n1c2ccccc2c2ccc3c4ccccc4oc3c21]

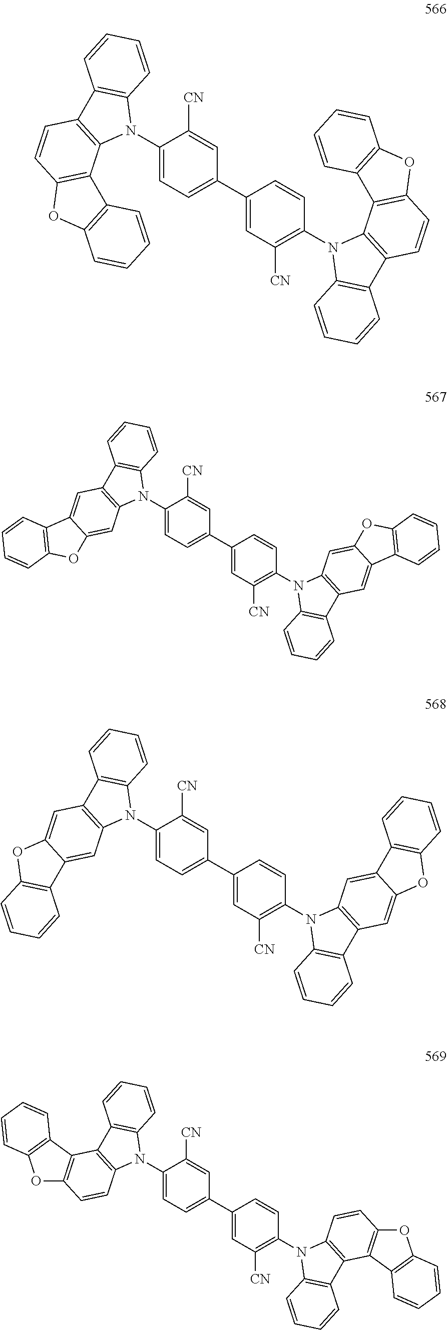 [SMILES: N#Cc1cc(-c2ccc(-n3c4ccccc4c4ccc5oc6ccccc6c5c43)c(C#N)c2)ccc1-n1c2ccccc2c2ccc3oc4ccccc4c3c21 ; N#Cc1cc(-c2ccc(-n3c4ccccc4c4cc5c(cc43)oc3ccccc35)c(C#N)c2)ccc1-n1c2ccccc2c2cc3c(cc21)oc1ccccc13 ; N#Cc1cc(-c2ccc(-n3c4ccccc4c4cc5oc6ccccc6c5cc43)c(C#N)c2)ccc1-n1c2ccccc2c2cc3oc4ccccc4c3cc21 ; N#Cc1cc(-c2ccc(-n3c4ccccc4c4c5c(ccc43)oc3ccccc35)c(C#N)c2)ccc1-n1c2ccccc2c2c3c(ccc21)oc1ccccc13]

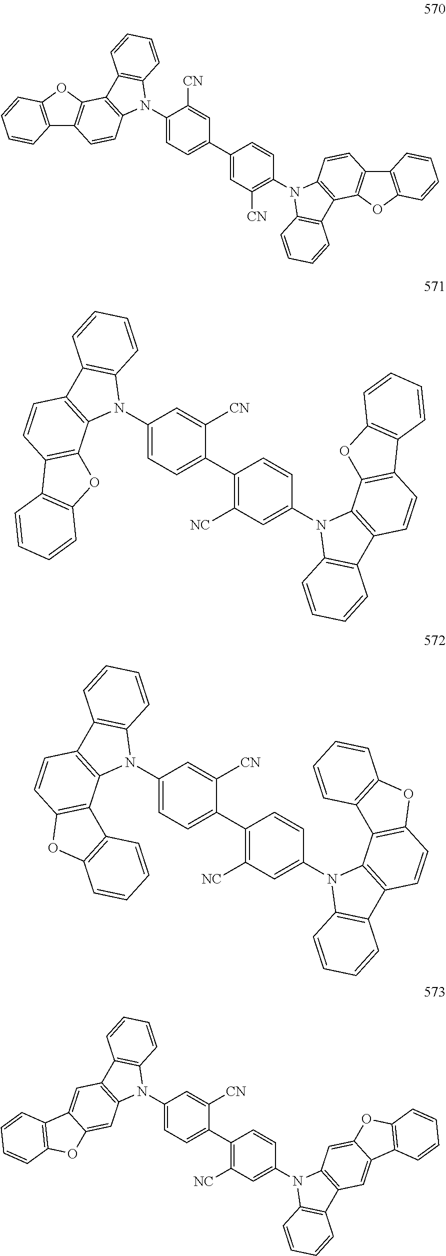 [SMILES: N#Cc1cc(-c2ccc(-n3c4ccccc4c4c5oc6ccccc6c5ccc43)c(C#N)c2)ccc1-n1c2ccccc2c2c3oc4ccccc4c3ccc21 ; N#Cc1cc(-n2c3ccccc3c3ccc4c5ccccc5oc4c32)ccc1-c1ccc(-n2c3ccccc3c3ccc4c5ccccc5oc4c32)cc1C#N ; N#Cc1cc(-n2c3ccccc3c3ccc4oc5ccccc5c4c32)ccc1-c1ccc(-n2c3ccccc3c3ccc4oc5ccccc5c4c32)cc1C#N ; N#Cc1cc(-n2c3ccccc3c3cc4c(cc32)oc2ccccc24)ccc1-c1ccc(-n2c3ccccc3c3cc4c(cc32)oc2ccccc24)cc1C#N]

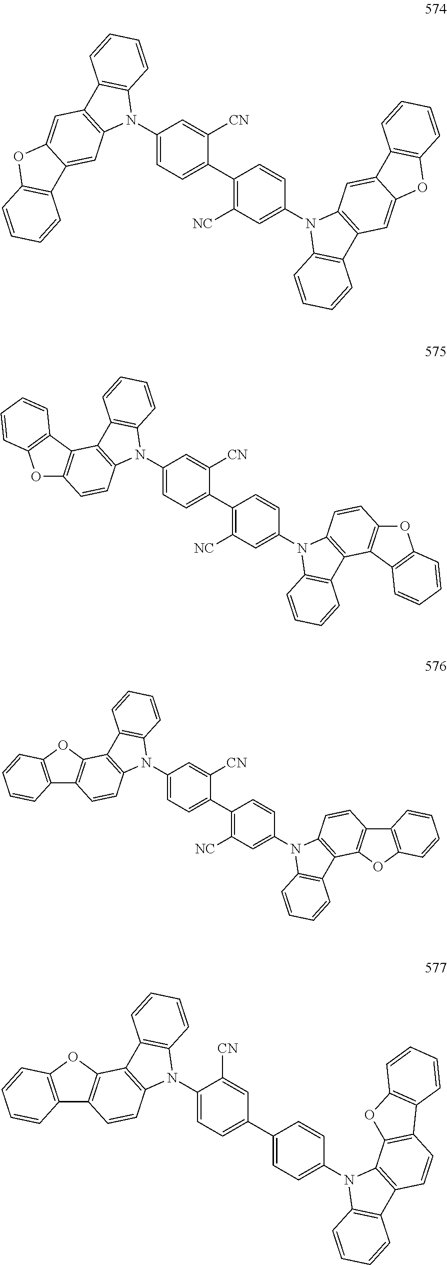 [SMILES: N#Cc1cc(-n2c3ccccc3c3cc4oc5ccccc5c4cc32)ccc1-c1ccc(-n2c3ccccc3c3cc4oc5ccccc5c4cc32)cc1C#N ; N#Cc1cc(-n2c3ccccc3c3c4c(ccc32)oc2ccccc24)ccc1-c1ccc(-n2c3ccccc3c3c4c(ccc32)oc2ccccc24)cc1C#N ; N#Cc1cc(-n2c3ccccc3c3c4oc5ccccc5c4ccc32)ccc1-c1ccc(-n2c3ccccc3c3c4oc5ccccc5c4ccc32)cc1C#N ; N#Cc1cc(-c2ccc(-n3c4ccccc4c4ccc5c6ccccc6oc5c43)cc2)ccc1-n1c2ccccc2c2c3oc4ccccc4c3ccc21]

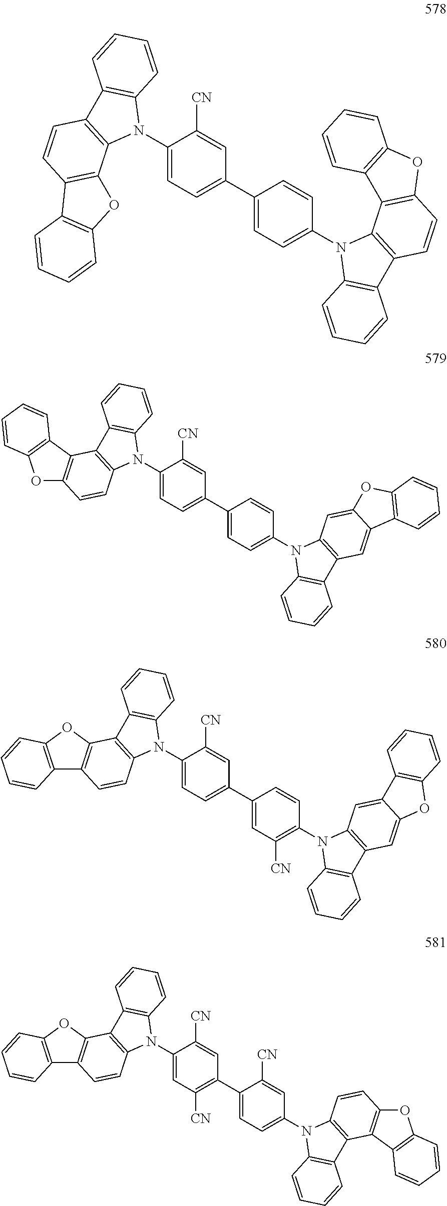 [SMILES: N#Cc1cc(-c2ccc(-n3c4ccccc4c4ccc5oc6ccccc6c5c43)cc2)ccc1-n1c2ccccc2c2ccc3c4ccccc4oc3c21 ; N#Cc1cc(-c2ccc(-n3c4ccccc4c4cc5c(cc43)oc3ccccc35)cc2)ccc1-n1c2ccccc2c2c3c(ccc21)oc1ccccc13 ; N#Cc1cc(-c2ccc(-n3c4ccccc4c4c5oc6ccccc6c5ccc43)c(C#N)c2)ccc1-n1c2ccccc2c2cc3oc4ccccc4c3cc21 ; N#Cc1cc(-n2c3ccccc3c3c4c(ccc32)oc2ccccc24)ccc1-c1cc(C#N)c(-n2c3ccccc3c3c4oc5ccccc5c4ccc32)cc1C#N]

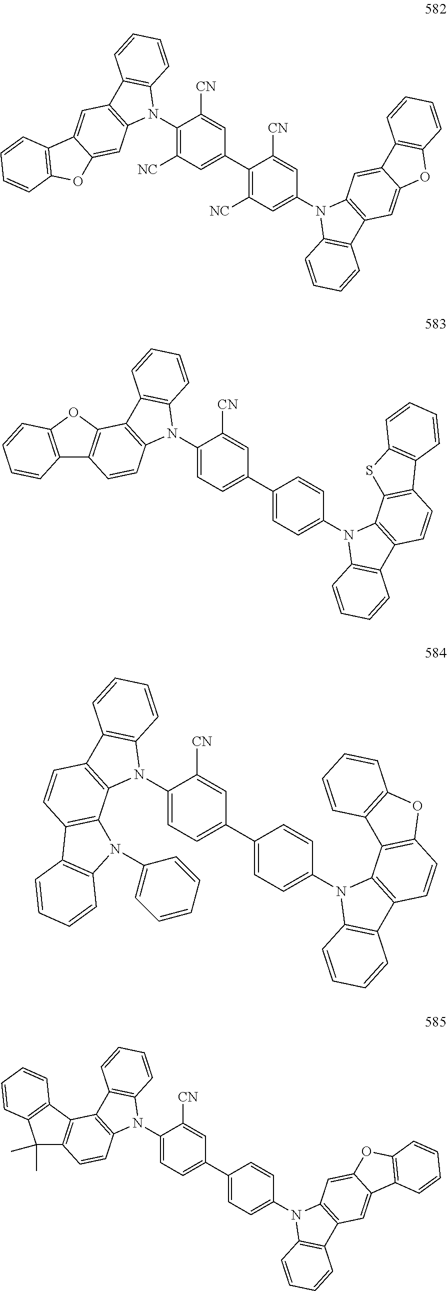 [SMILES: N#Cc1cc(-n2c3ccccc3c3cc4oc5ccccc5c4cc32)cc(C#N)c1-c1cc(C#N)c(-n2c3ccccc3c3cc4c(cc32)oc2ccccc24)c(C#N)c1 ; N#Cc1cc(-c2ccc(-n3c4ccccc4c4ccc5c6ccccc6sc5c43)cc2)ccc1-n1c2ccccc2c2c3oc4ccccc4c3ccc21 ; N#Cc1cc(-c2ccc(-n3c4ccccc4c4ccc5oc6ccccc6c5c43)cc2)ccc1-n1c2ccccc2c2ccc3c4ccccc4n(-c4ccccc4)c3c21 ; CC1(C)c2ccccc2-c2c1ccc1c2c2ccccc2n1-c1ccc(-c2ccc(-n3c4ccccc4c4cc5c(cc43)oc3ccccc35)cc2)cc1C#N]

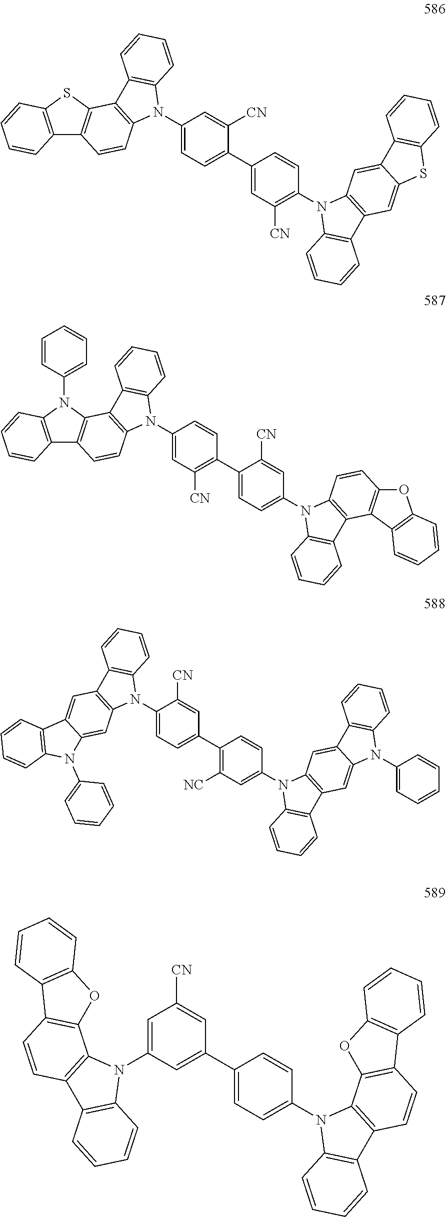 [SMILES: N#Cc1cc(-n2c3ccccc3c3c4sc5ccccc5c4ccc32)ccc1-c1ccc(-n2c3ccccc3c3cc4sc5ccccc5c4cc32)c(C#N)c1 ; N#Cc1cc(-n2c3ccccc3c3c4c(ccc32)oc2ccccc24)ccc1-c1ccc(-n2c3ccccc3c3c2ccc2c4ccccc4n(-c4ccccc4)c23)cc1C#N ; N#Cc1cc(-n2c3ccccc3c3cc4c(cc32)c2ccccc2n4-c2ccccc2)ccc1-c1ccc(-n2c3ccccc3c3cc4c5ccccc5n(-c5ccccc5)c4cc32)c(C#N)c1 ; N#Cc1cc(-c2ccc(-n3c4ccccc4c4ccc5c6ccccc6oc5c43)cc2)cc(-n2c3ccccc3c3ccc4c5ccccc5oc4c32)c1]

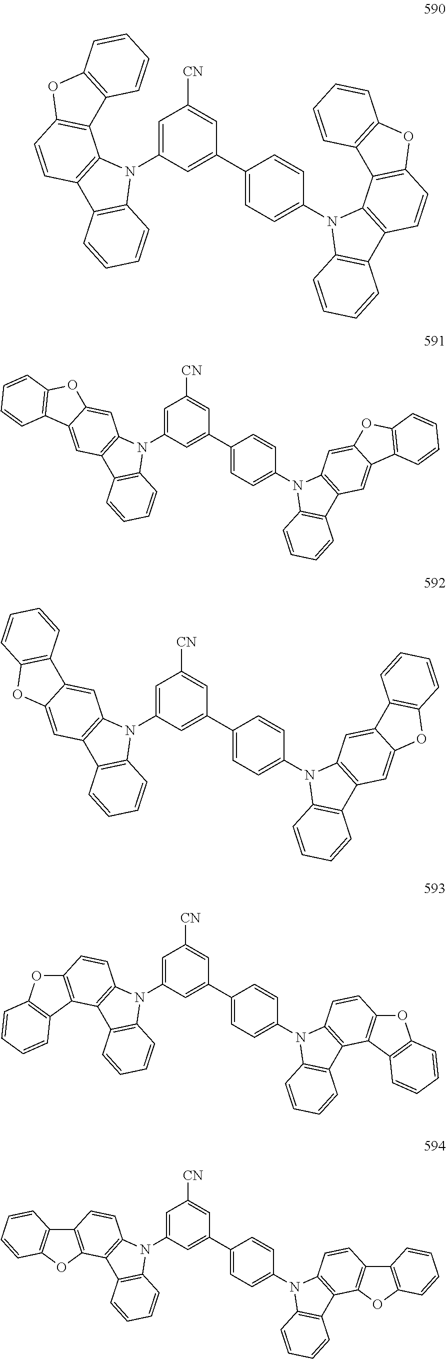 [SMILES: N#Cc1cc(-c2ccc(-n3c4ccccc4c4ccc5oc6ccccc6c5c43)cc2)cc(-n2c3ccccc3c3ccc4oc5ccccc5c4c32)c1 ; N#Cc1cc(-c2ccc(-n3c4ccccc4c4cc5c(cc43)oc3ccccc35)cc2)cc(-n2c3ccccc3c3cc4c(cc32)oc2ccccc24)c1 ; N#Cc1cc(-c2ccc(-n3c4ccccc4c4cc5oc6ccccc6c5cc43)cc2)cc(-n2c3ccccc3c3cc4oc5ccccc5c4cc32)c1 ; N#Cc1cc(-c2ccc(-n3c4ccccc4c4c5c(ccc43)oc3ccccc35)cc2)cc(-n2c3ccccc3c3c4c(ccc32)oc2ccccc24)c1 ; N#Cc1cc(-c2ccc(-n3c4ccccc4c4c5oc6ccccc6c5ccc43)cc2)cc(-n2c3ccccc3c3c4oc5ccccc5c4ccc32)c1]

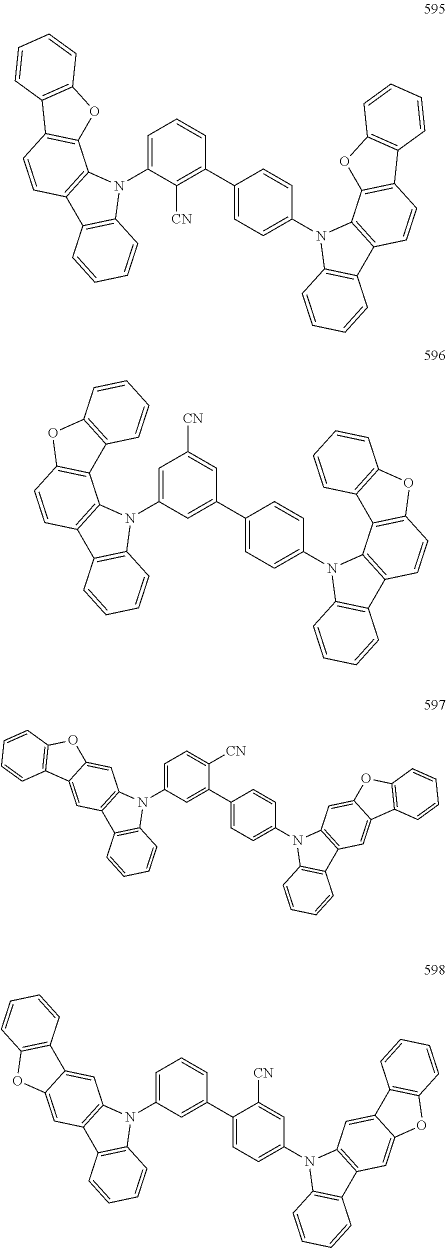 [SMILES: N#Cc1c(-c2ccc(-n3c4ccccc4c4ccc5c6ccccc6oc5c43)cc2)cccc1-n1c2ccccc2c2ccc3c4ccccc4oc3c21 ; N#Cc1cc(-c2ccc(-n3c4ccccc4c4ccc5oc6ccccc6c5c43)cc2)cc(-n2c3ccccc3c3ccc4oc5ccccc5c4c32)c1 ; N#Cc1ccc(-n2c3ccccc3c3cc4c(cc32)oc2ccccc24)cc1-c1ccc(-n2c3ccccc3c3cc4c(cc32)oc2ccccc24)cc1 ; N#Cc1cc(-n2c3ccccc3c3cc4oc5ccccc5c4cc32)ccc1-c1cccc(-n2c3ccccc3c3cc4oc5ccccc5c4cc32)c1]

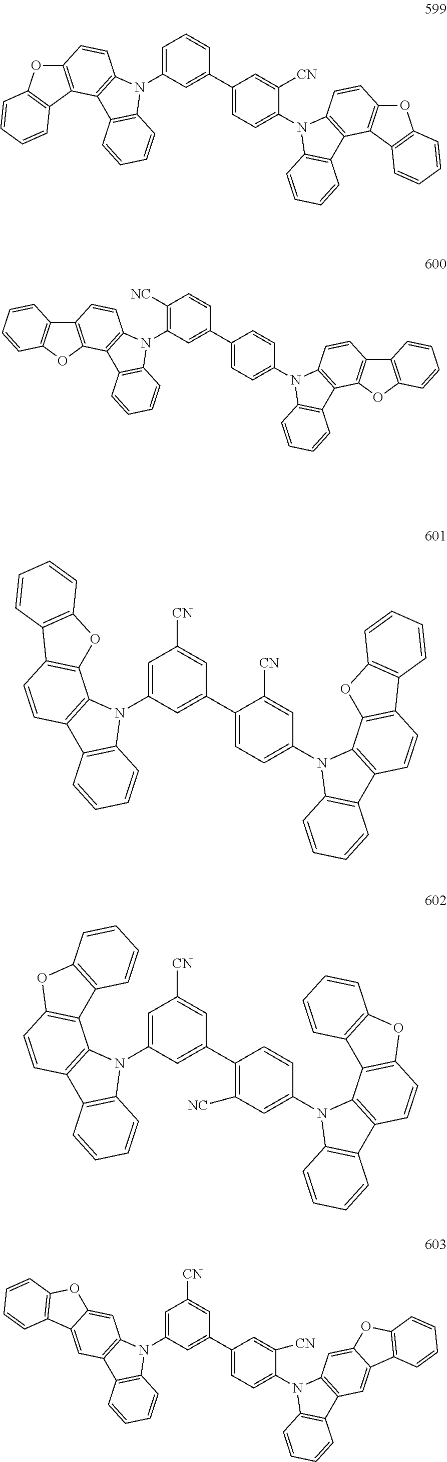 [SMILES: N#Cc1cc(-c2cccc(-n3c4ccccc4c4c5c(ccc43)oc3ccccc35)c2)ccc1-n1c2ccccc2c2c3c(ccc21)oc1ccccc13 ; N#Cc1ccc(-c2ccc(-n3c4ccccc4c4c5oc6ccccc6c5ccc43)cc2)cc1-n1c2ccccc2c2c3oc4ccccc4c3ccc21 ; N#Cc1cc(-c2ccc(-n3c4ccccc4c4ccc5c6ccccc6oc5c43)cc2C#N)cc(-n2c3ccccc3c3ccc4c5ccccc5oc4c32)c1 ; N#Cc1cc(-c2ccc(-n3c4ccccc4c4ccc5oc6ccccc6c5c43)cc2C#N)cc(-n2c3ccccc3c3ccc4oc5ccccc5c4c32)c1 ; N#Cc1cc(-c2ccc(-n3c4ccccc4c4cc5c(cc43)oc3ccccc35)c(C#N)c2)cc(-n2c3ccccc3c3cc4c(cc32)oc2ccccc24)c1]

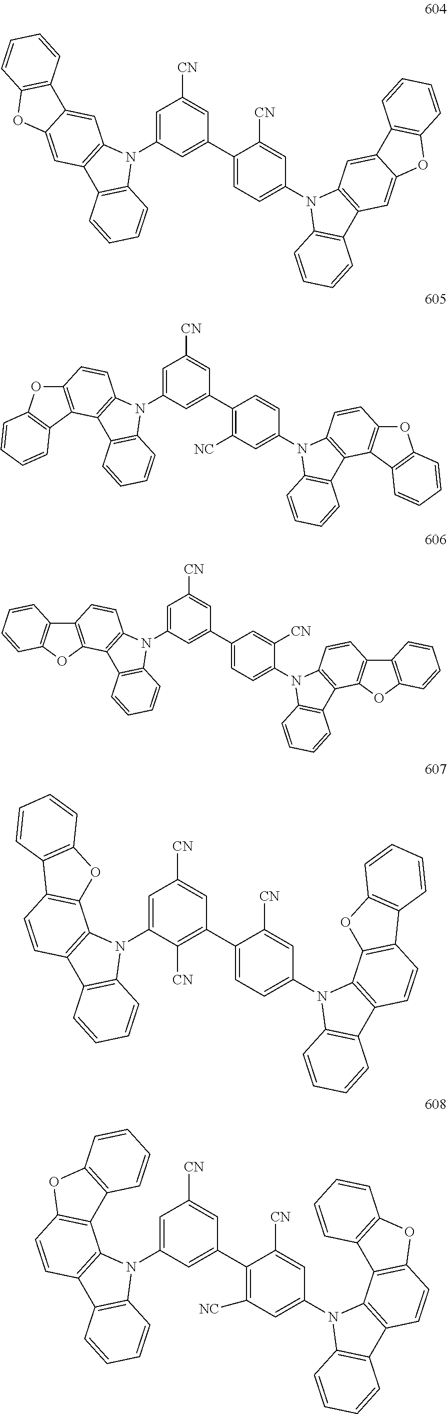 [SMILES: N#Cc1cc(-c2ccc(-n3c4ccccc4c4cc5oc6ccccc6c5cc43)cc2C#N)cc(-n2c3ccccc3c3cc4oc5ccccc5c4cc32)c1 ; N#Cc1cc(-c2ccc(-n3c4ccccc4c4c5c(ccc43)oc3ccccc35)cc2C#N)cc(-n2c3ccccc3c3c4c(ccc32)oc2ccccc24)c1 ; N#Cc1cc(-c2ccc(-n3c4ccccc4c4c5oc6ccccc6c5ccc43)c(C#N)c2)cc(-n2c3ccccc3c3c4oc5ccccc5c4ccc32)c1 ; N#Cc1cc(-c2ccc(-n3c4ccccc4c4ccc5c6ccccc6oc5c43)cc2C#N)c(C#N)c(-n2c3ccccc3c3ccc4c5ccccc5oc4c32)c1 ; N#Cc1cc(-c2c(C#N)cc(-n3c4ccccc4c4ccc5oc6ccccc6c5c43)cc2C#N)cc(-n2c3ccccc3c3ccc4oc5ccccc5c4c32)c1]

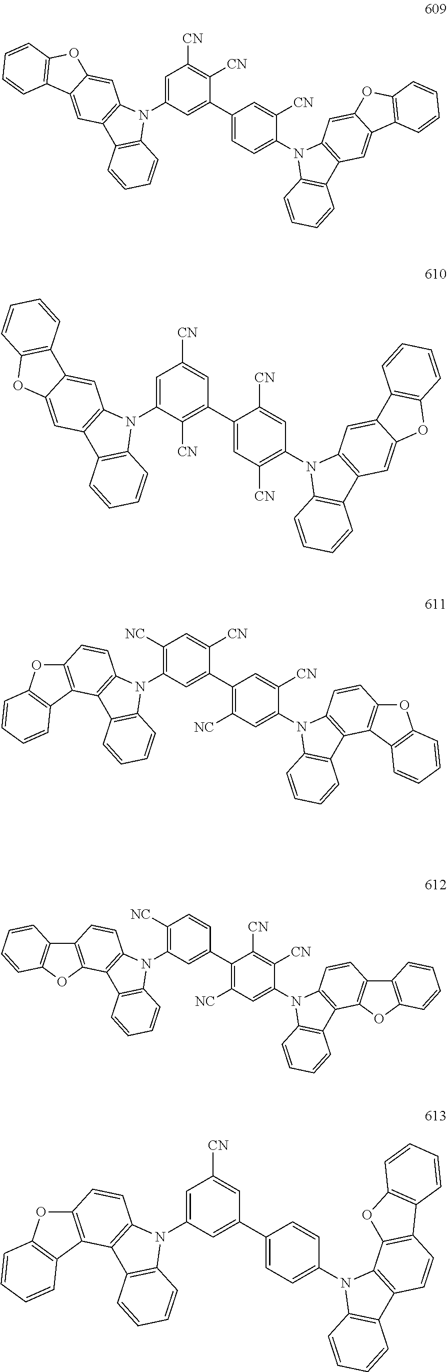

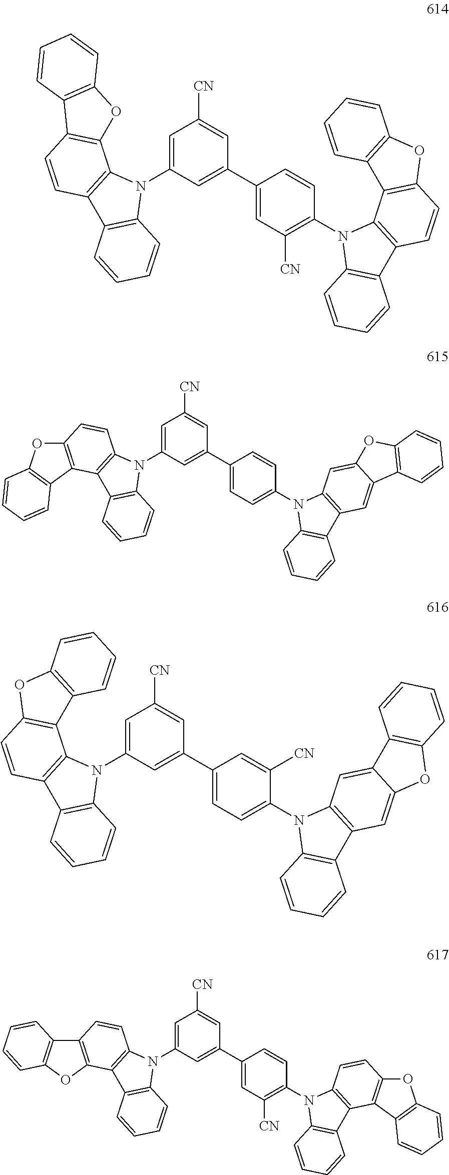 [SMILES: N#Cc1cc(-c2ccc(-n3c4ccccc4c4ccc5oc6ccccc6c5c43)c(C#N)c2)cc(-n2c3ccccc3c3ccc4c5ccccc5oc4c32)c1 ; N#Cc1cc(-c2ccc(-n3c4ccccc4c4cc5c(cc43)oc3ccccc35)cc2)cc(-n2c3ccccc3c3c4c(ccc32)oc2ccccc24)c1 ; N#Cc1cc(-c2ccc(-n3c4ccccc4c4cc5oc6ccccc6c5cc43)c(C#N)c2)cc(-n2c3ccccc3c3ccc4oc5ccccc5c4c32)c1 ; N#Cc1cc(-c2ccc(-n3c4ccccc4c4c5c(ccc43)oc3ccccc35)c(C#N)c2)cc(-n2c3ccccc3c3c4oc5ccccc5c4ccc32)c1]

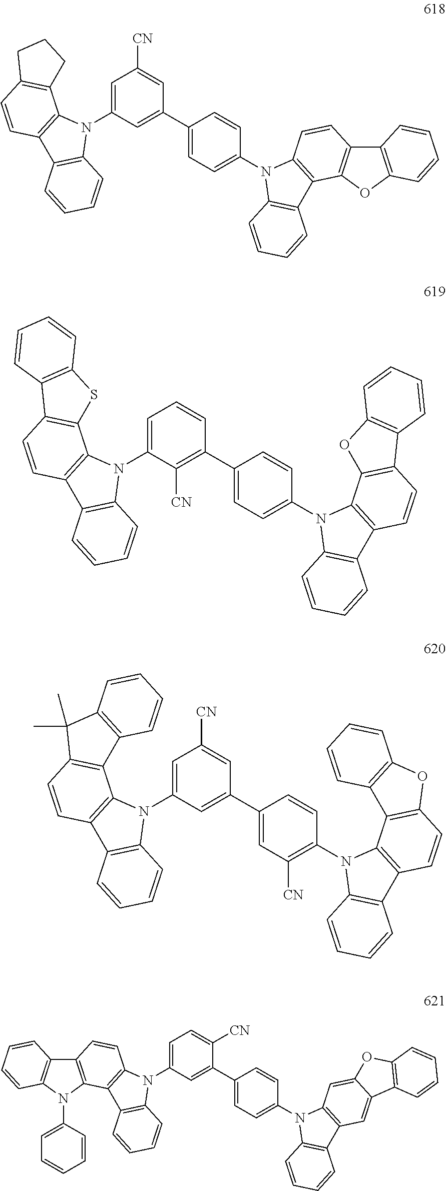 [SMILES: N#Cc1cc(-c2ccc(-n3c4ccccc4c4c5oc6ccccc6c5ccc43)cc2)cc(-n2c3ccccc3c3ccc4c(c32)CCC4)c1 ; N#Cc1c(-c2ccc(-n3c4ccccc4c4ccc5c6ccccc6oc5c43)cc2)cccc1-n1c2ccccc2c2ccc3c4ccccc4sc3c21 ; CC1(C)c2ccccc2-c2c1ccc1c3ccccc3n(-c3cc(C#N)cc(-c4ccc(-n5c6ccccc6c6ccc7oc8ccccc8c7c65)c(C#N)c4)c3)c21 ; N#Cc1ccc(-n2c3ccccc3c3c2ccc2c4ccccc4n(-c4ccccc4)c23)cc1-c1ccc(-n2c3ccccc3c3cc4c(cc32)oc2ccccc24)cc1]

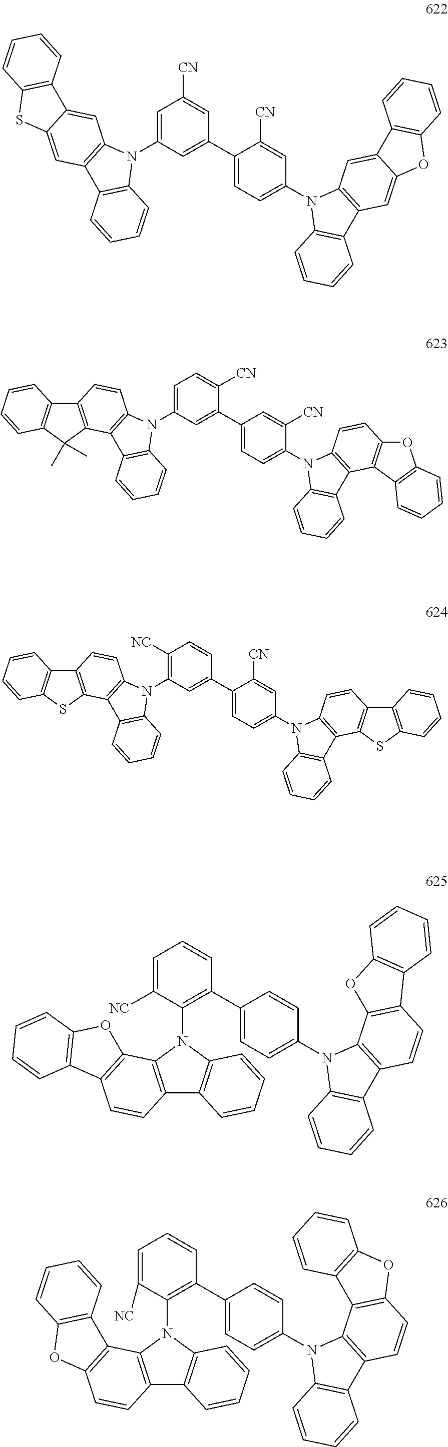 [SMILES: N#Cc1cc(-c2ccc(-n3c4ccccc4c4cc5oc6ccccc6c5cc43)cc2C#N)cc(-n2c3ccccc3c3cc4sc5ccccc5c4cc32)c1 ; CC1(C)c2ccccc2-c2ccc3c(c21)c1ccccc1n3-c1ccc(C#N)c(-c2ccc(-n3c4ccccc4c4c5c(ccc43)oc3ccccc35)c(C#N)c2)c1 ; N#Cc1cc(-n2c3ccccc3c3c4sc5ccccc5c4ccc32)ccc1-c1ccc(C#N)c(-n2c3ccccc3c3c4sc5ccccc5c4ccc32)c1 ; N#Cc1cccc(-c2ccc(-n3c4ccccc4c4ccc5c6ccccc6oc5c43)cc2)c1-n1c2ccccc2c2ccc3c4ccccc4oc3c21 ; N#Cc1cccc(-c2ccc(-n3c4ccccc4c4ccc5oc6ccccc6c5c43)cc2)c1-n1c2ccccc2c2ccc3oc4ccccc4c3c21]

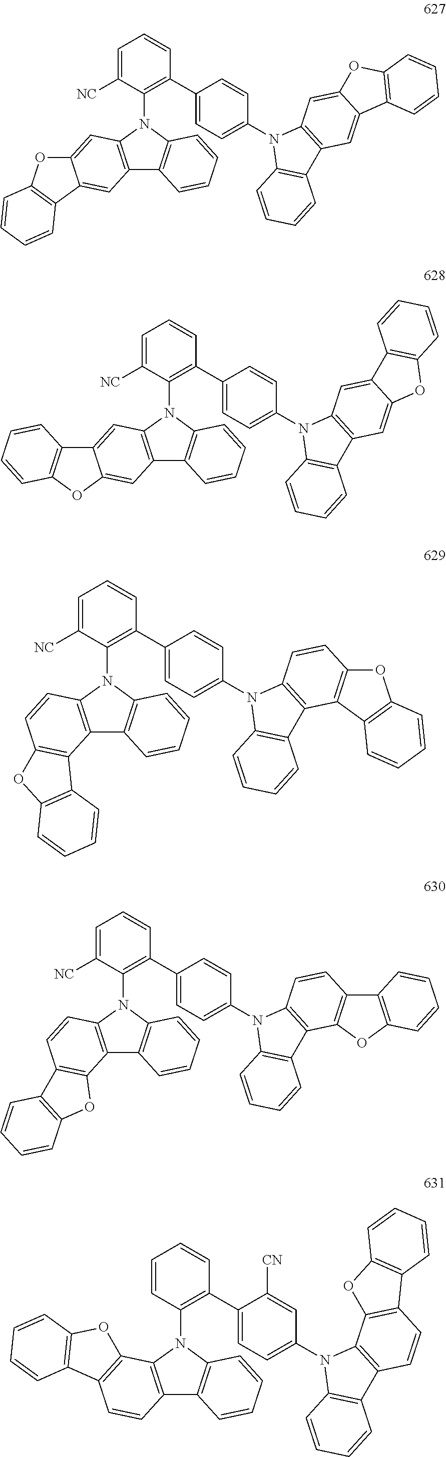 [SMILES: N#Cc1cccc(-c2ccc(-n3c4ccccc4c4cc5c(cc43)oc3ccccc35)cc2)c1-n1c2ccccc2c2cc3c(cc21)oc1ccccc13 ; N#Cc1cccc(-c2ccc(-n3c4ccccc4c4cc5oc6ccccc6c5cc43)cc2)c1-n1c2ccccc2c2cc3oc4ccccc4c3cc21 ; N#Cc1cccc(-c2ccc(-n3c4ccccc4c4c5c(ccc43)oc3ccccc35)cc2)c1-n1c2ccccc2c2c3c(ccc21)oc1ccccc13 ; N#Cc1cccc(-c2ccc(-n3c4ccccc4c4c5oc6ccccc6c5ccc43)cc2)c1-n1c2ccccc2c2c3oc4ccccc4c3ccc21 ; N#Cc1cc(-n2c3ccccc3c3ccc4c5ccccc5oc4c32)ccc1-c1ccccc1-n1c2ccccc2c2ccc3c4ccccc4oc3c21]

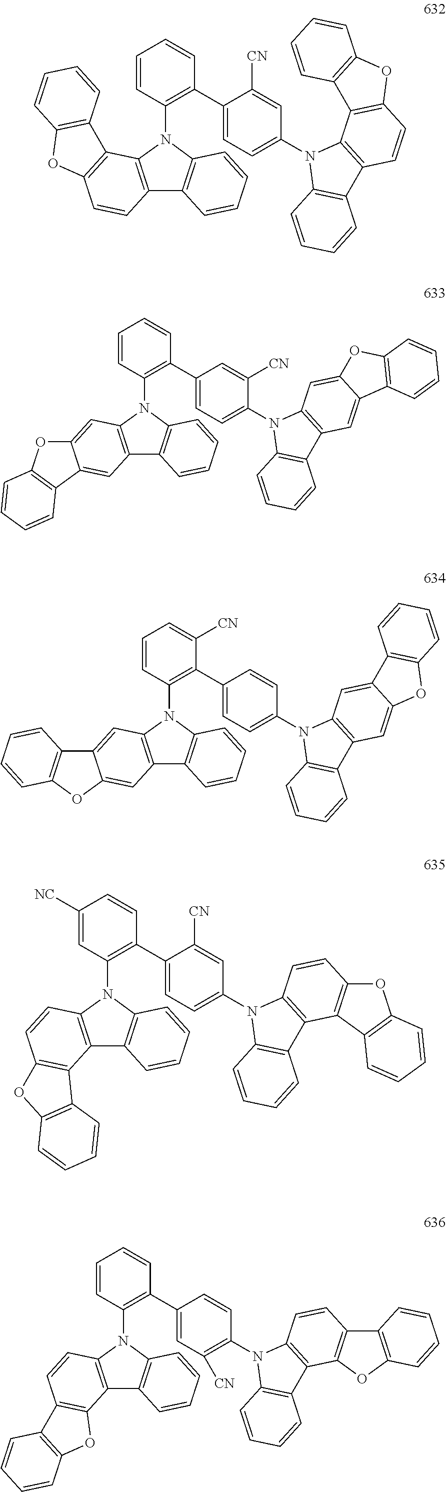 [SMILES: N#Cc1cc(-n2c3ccccc3c3ccc4oc5ccccc5c4c32)ccc1-c1ccccc1-n1c2ccccc2c2ccc3oc4ccccc4c3c21 ; N#Cc1cc(-c2ccccc2-n2c3ccccc3c3cc4c(cc32)oc2ccccc24)ccc1-n1c2ccccc2c2cc3c(cc21)oc1ccccc13 ; N#Cc1cccc(-n2c3ccccc3c3cc4oc5ccccc5c4cc32)c1-c1ccc(-n2c3ccccc3c3cc4oc5ccccc5c4cc32)cc1 ; N#Cc1ccc(-c2ccc(-n3c4ccccc4c4c5c(ccc43)oc3ccccc35)cc2C#N)c(-n2c3ccccc3c3c4c(ccc32)oc2ccccc24)c1 ; N#Cc1cc(-c2ccccc2-n2c3ccccc3c3c4oc5ccccc5c4ccc32)ccc1-n1c2ccccc2c2c3oc4ccccc4c3ccc21]

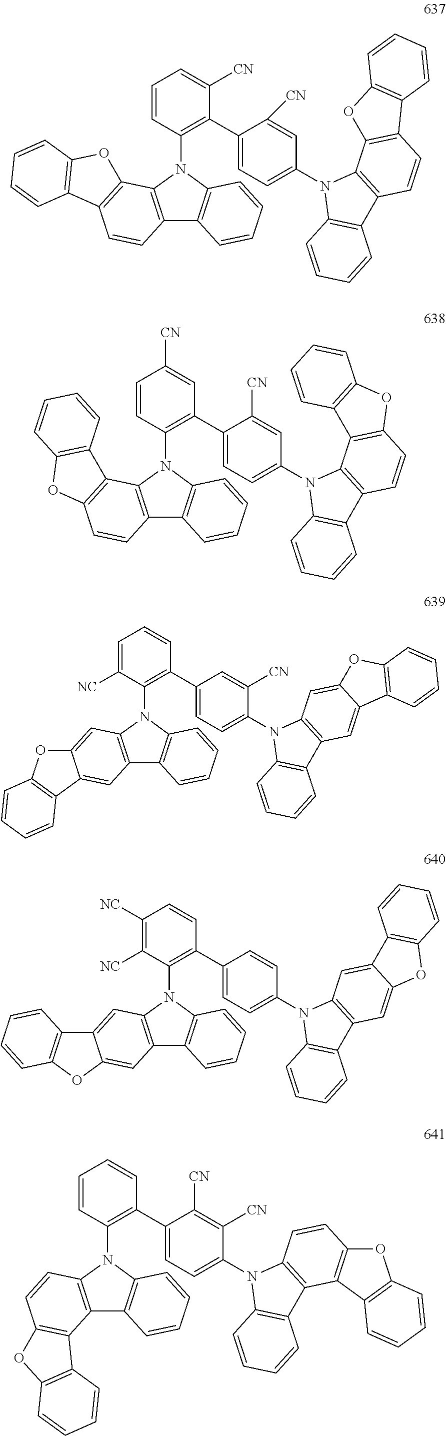 [SMILES: N#Cc1cc(-n2c3ccccc3c3ccc4c5ccccc5oc4c32)ccc1-c1c(C#N)cccc1-n1c2ccccc2c2ccc3c4ccccc4oc3c21 ; N#Cc1ccc(-n2c3ccccc3c3ccc4oc5ccccc5c4c32)c(-c2ccc(-n3c4ccccc4c4ccc5oc6ccccc6c5c43)cc2C#N)c1 ; N#Cc1cc(-c2cccc(C#N)c2-n2c3ccccc3c3cc4c(cc32)oc2ccccc24)ccc1-n1c2ccccc2c2cc3c(cc21)oc1ccccc13 ; N#Cc1ccc(-c2ccc(-n3c4ccccc4c4cc5oc6ccccc6c5cc43)cc2)c(-n2c3ccccc3c3cc4oc5ccccc5c4cc32)c1C#N ; N#Cc1c(-c2ccccc2-n2c3ccccc3c3c4c(ccc32)oc2ccccc24)ccc(-n2c3ccccc3c3c4c(ccc32)oc2ccccc24)c1C#N]

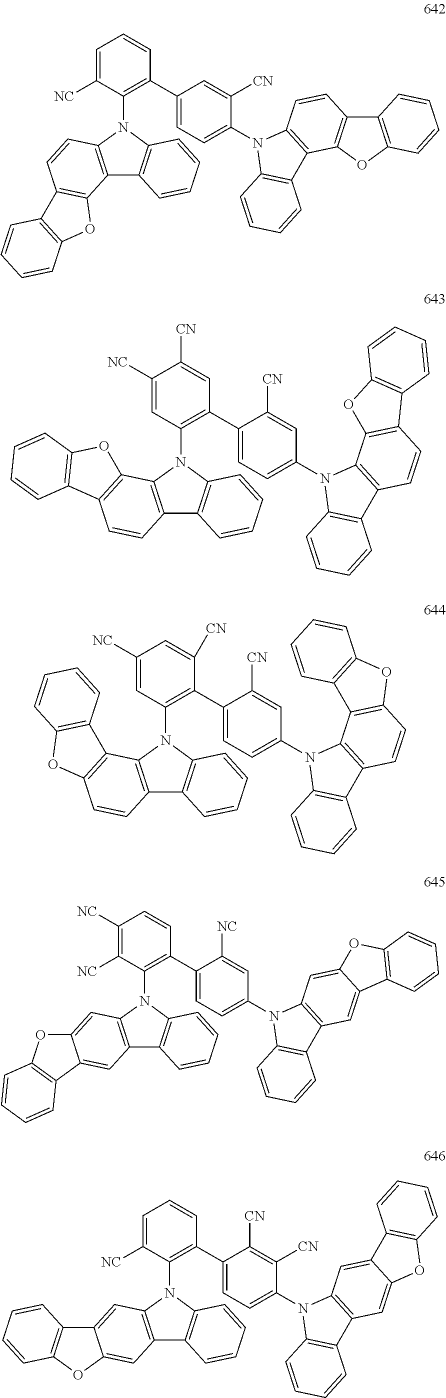

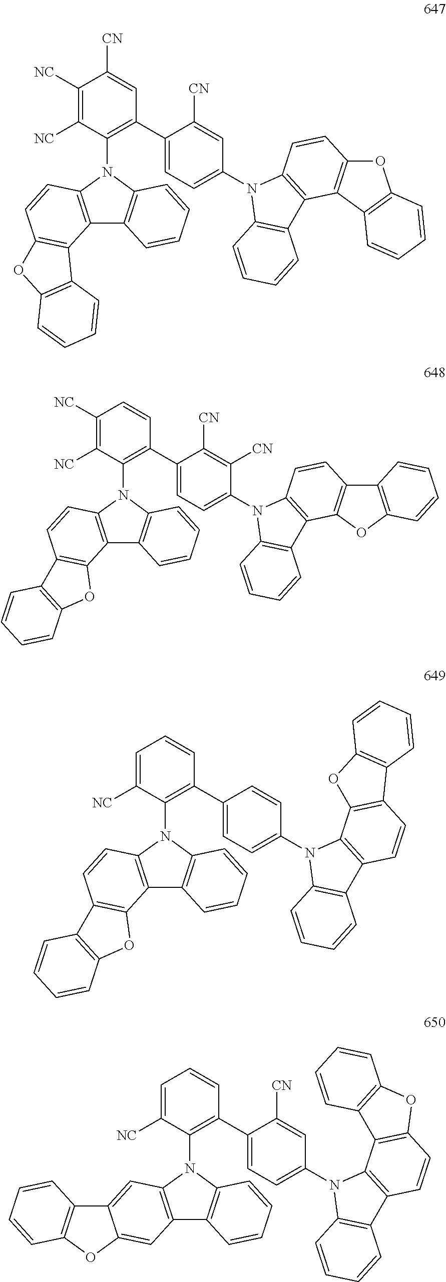 [SMILES: N#Cc1cc(-n2c3ccccc3c3c4c(ccc32)oc2ccccc24)ccc1-c1cc(C#N)c(C#N)c(C#N)c1-n1c2ccccc2c2c3c(ccc21)oc1ccccc13 ; N#Cc1ccc(-c2ccc(-n3c4ccccc4c4c5oc6ccccc6c5ccc43)c(C#N)c2C#N)c(-n2c3ccccc3c3c4oc5ccccc5c4ccc32)c1C#N ; N#Cc1cccc(-c2ccc(-n3c4ccccc4c4ccc5c6ccccc6oc5c43)cc2)c1-n1c2ccccc2c2c3oc4ccccc4c3ccc21 ; N#Cc1cc(-n2c3ccccc3c3ccc4oc5ccccc5c4c32)ccc1-c1cccc(C#N)c1-n1c2ccccc2c2cc3oc4ccccc4c3cc21]

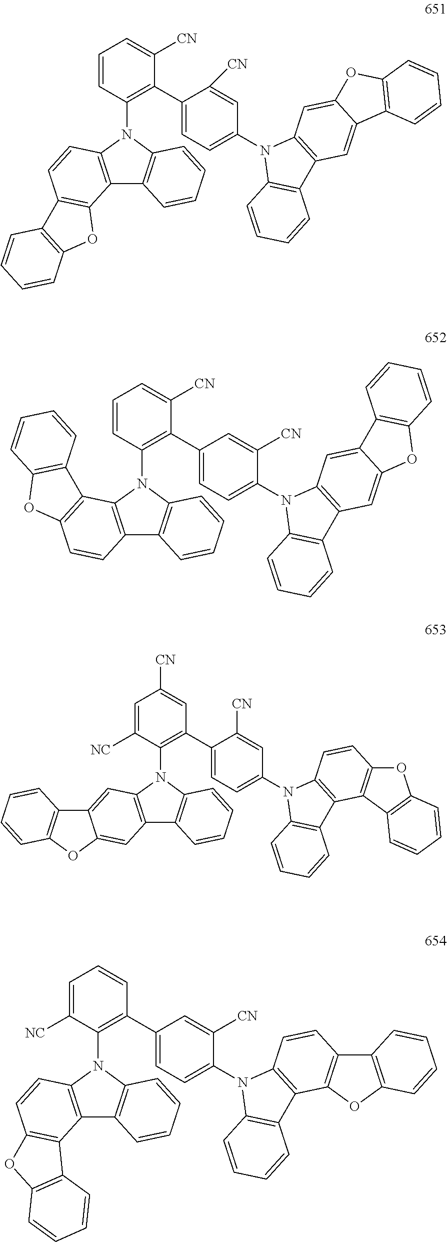 [SMILES: N#Cc1cc(-n2c3ccccc3c3cc4c(cc32)oc2ccccc24)ccc1-c1c(C#N)cccc1-n1c2ccccc2c2c3oc4ccccc4c3ccc21 ; N#Cc1cc(-c2c(C#N)cccc2-n2c3ccccc3c3ccc4oc5ccccc5c4c32)ccc1-n1c2ccccc2c2cc3oc4ccccc4c3cc21 ; N#Cc1cc(C#N)c(-n2c3ccccc3c3cc4oc5ccccc5c4cc32)c(-c2ccc(-n3c4ccccc4c4c5c(ccc43)oc3ccccc35)cc2C#N)c1 ; N#Cc1cc(-c2cccc(C#N)c2-n2c3ccccc3c3c4c(ccc32)oc2ccccc24)ccc1-n1c2ccccc2c2c3oc4ccccc4c3ccc21]

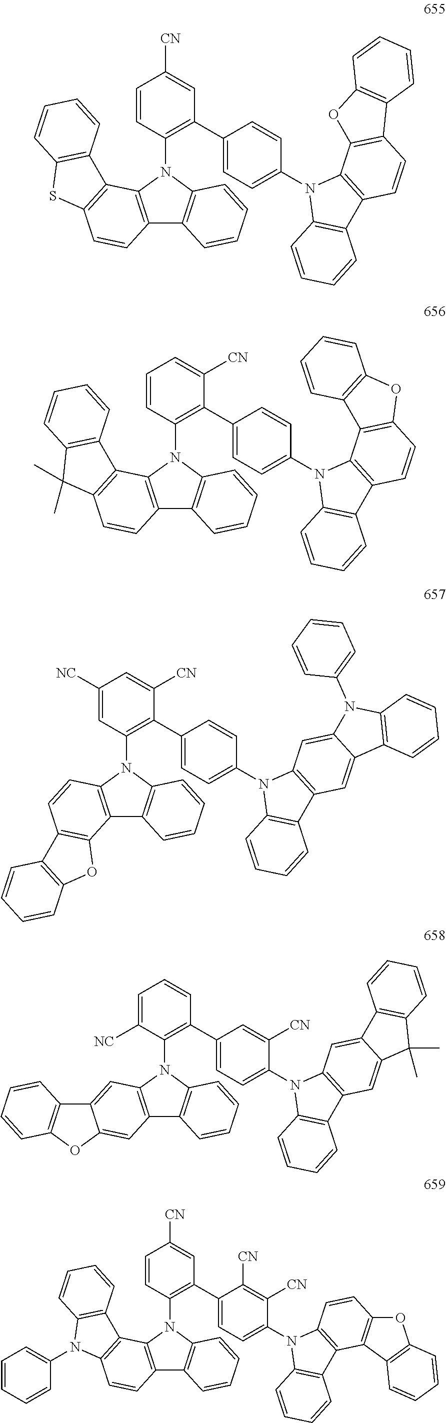

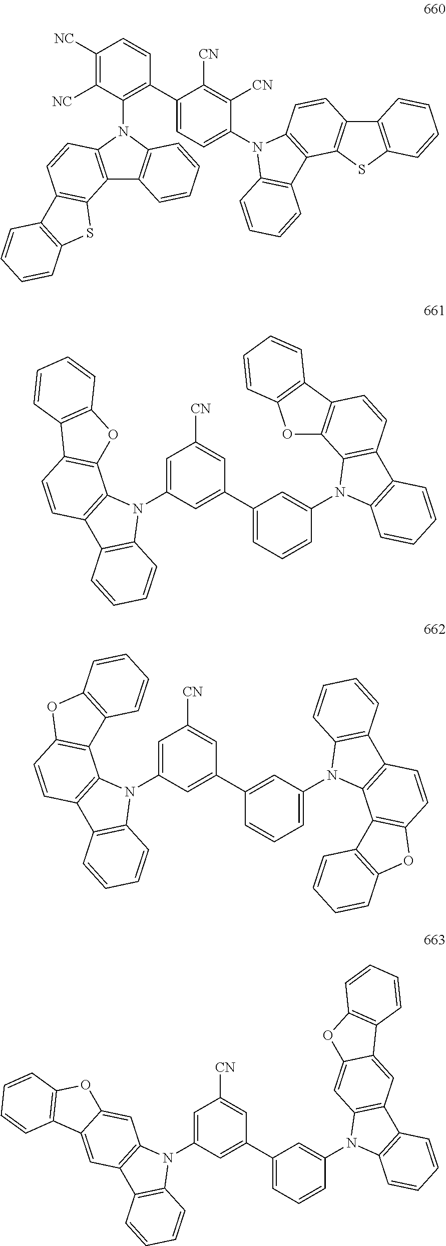 [SMILES: N#Cc1ccc(-c2ccc(-n3c4ccccc4c4c5sc6ccccc6c5ccc43)c(C#N)c2C#N)c(-n2c3ccccc3c3c4sc5ccccc5c4ccc32)c1C#N ; N#Cc1cc(-c2cccc(-n3c4ccccc4c4ccc5c6ccccc6oc5c43)c2)cc(-n2c3ccccc3c3ccc4c5ccccc5oc4c32)c1 ; N#Cc1cc(-c2cccc(-n3c4ccccc4c4ccc5oc6ccccc6c5c43)c2)cc(-n2c3ccccc3c3ccc4oc5ccccc5c4c32)c1 ; N#Cc1cc(-c2cccc(-n3c4ccccc4c4cc5c(cc43)oc3ccccc35)c2)cc(-n2c3ccccc3c3cc4c(cc32)oc2ccccc24)c1]

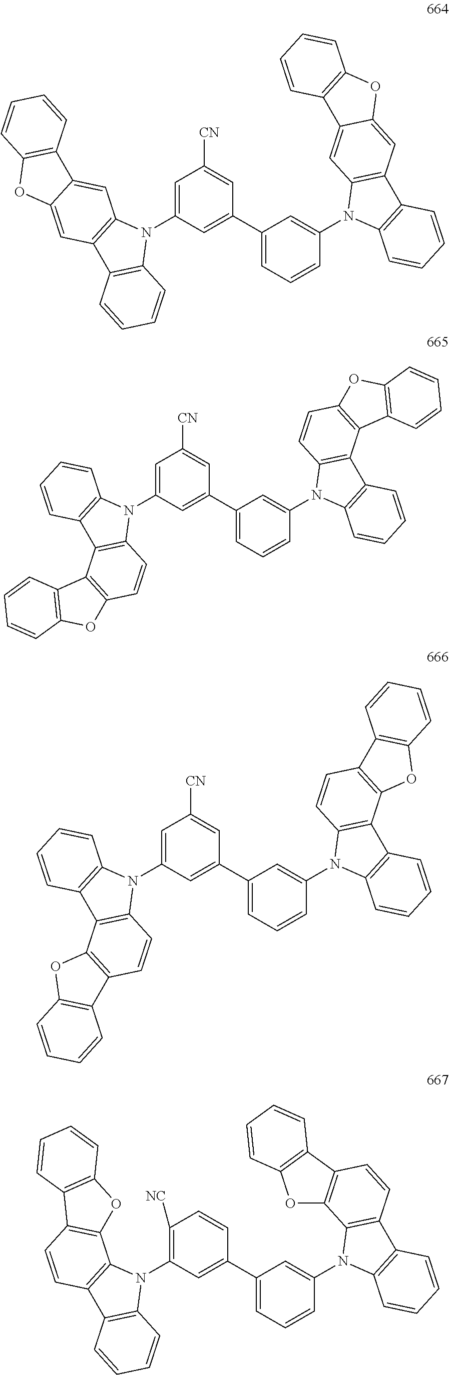 [SMILES: N#Cc1cc(-c2cccc(-n3c4ccccc4c4cc5oc6ccccc6c5cc43)c2)cc(-n2c3ccccc3c3cc4oc5ccccc5c4cc32)c1 ; N#Cc1cc(-c2cccc(-n3c4ccccc4c4c5c(ccc43)oc3ccccc35)c2)cc(-n2c3ccccc3c3c4c(ccc32)oc2ccccc24)c1 ; N#Cc1cc(-c2cccc(-n3c4ccccc4c4c5oc6ccccc6c5ccc43)c2)cc(-n2c3ccccc3c3c4oc5ccccc5c4ccc32)c1 ; N#Cc1ccc(-c2cccc(-n3c4ccccc4c4ccc5c6ccccc6oc5c43)c2)cc1-n1c2ccccc2c2ccc3c4ccccc4oc3c21]

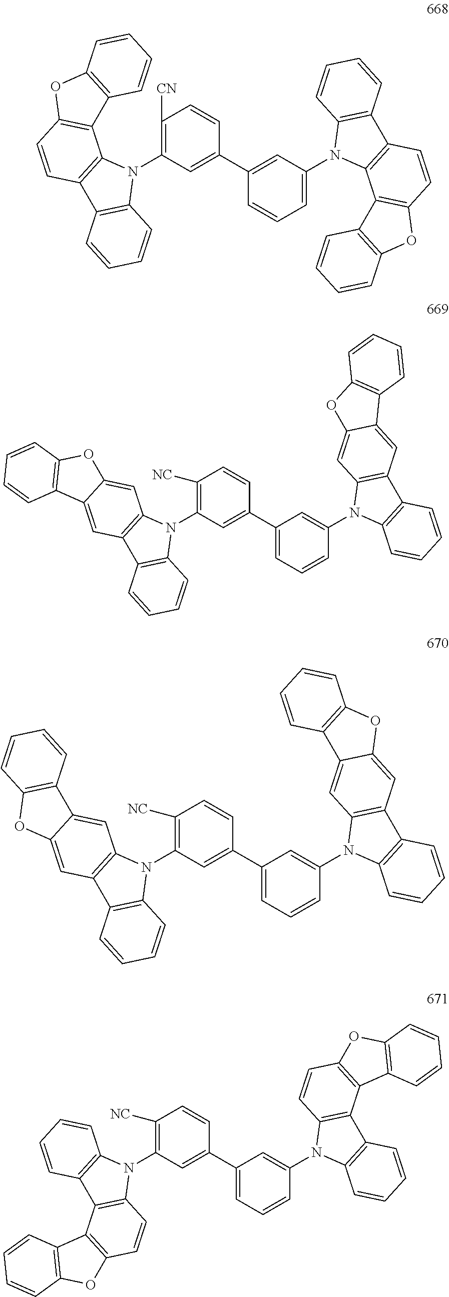 [SMILES: N#Cc1ccc(-c2cccc(-n3c4ccccc4c4ccc5oc6ccccc6c5c43)c2)cc1-n1c2ccccc2c2ccc3oc4ccccc4c3c21 ; N#Cc1ccc(-c2cccc(-n3c4ccccc4c4cc5c(cc43)oc3ccccc35)c2)cc1-n1c2ccccc2c2cc3c(cc21)oc1ccccc13 ; N#Cc1ccc(-c2cccc(-n3c4ccccc4c4cc5oc6ccccc6c5cc43)c2)cc1-n1c2ccccc2c2cc3oc4ccccc4c3cc21 ; N#Cc1ccc(-c2cccc(-n3c4ccccc4c4c5c(ccc43)oc3ccccc35)c2)cc1-n1c2ccccc2c2c3c(ccc21)oc1ccccc13]

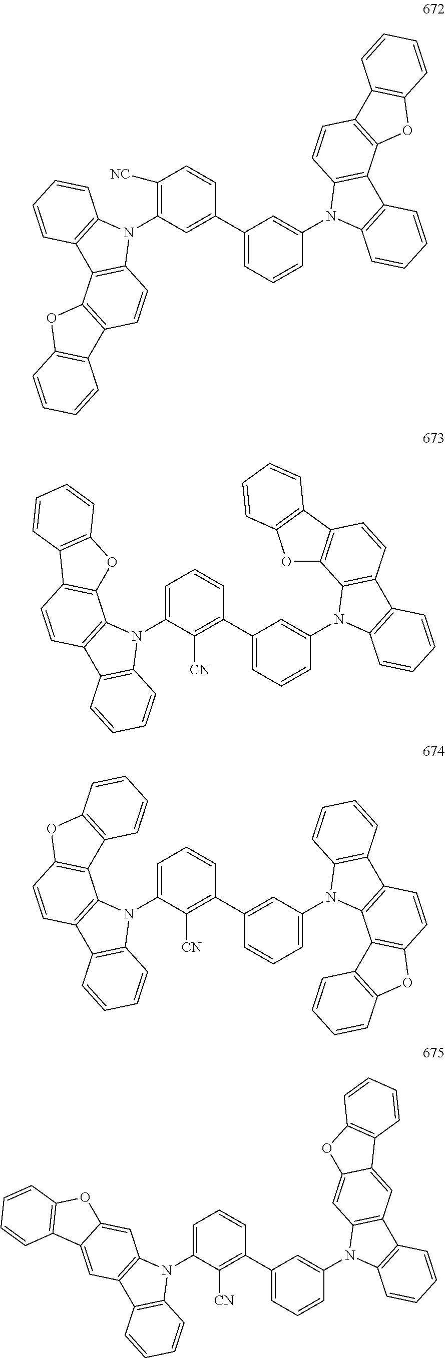

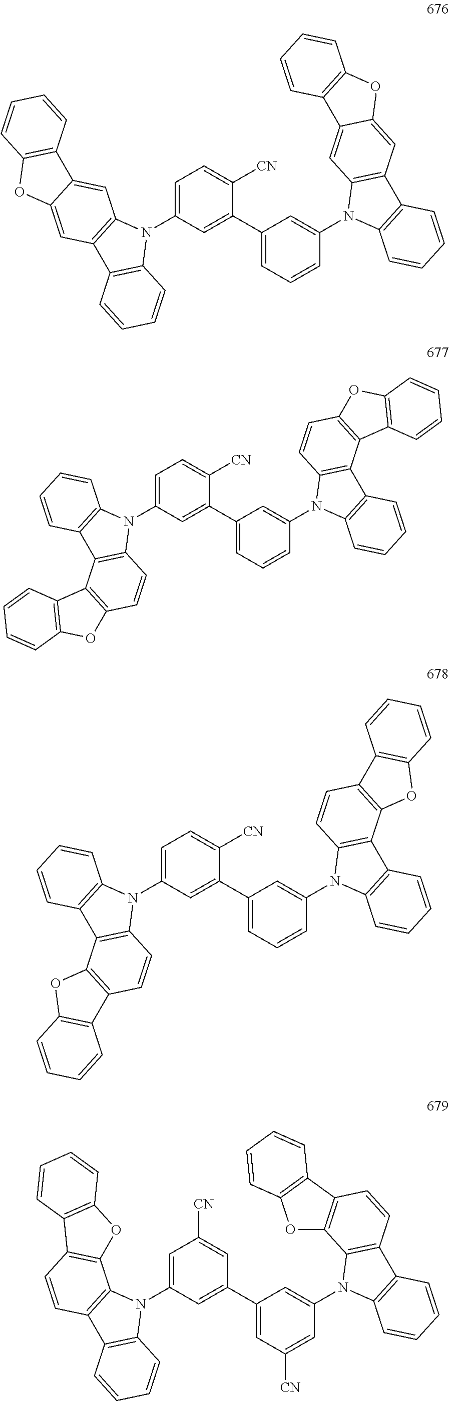 [SMILES: N#Cc1ccc(-n2c3ccccc3c3cc4oc5ccccc5c4cc32)cc1-c1cccc(-n2c3ccccc3c3cc4oc5ccccc5c4cc32)c1 ; N#Cc1ccc(-n2c3ccccc3c3c4c(ccc32)oc2ccccc24)cc1-c1cccc(-n2c3ccccc3c3c4c(ccc32)oc2ccccc24)c1 ; N#Cc1ccc(-n2c3ccccc3c3c4oc5ccccc5c4ccc32)cc1-c1cccc(-n2c3ccccc3c3c4oc5ccccc5c4ccc32)c1 ; N#Cc1cc(-c2cc(C#N)cc(-n3c4ccccc4c4ccc5c6ccccc6oc5c43)c2)cc(-n2c3ccccc3c3ccc4c5ccccc5oc4c32)c1]

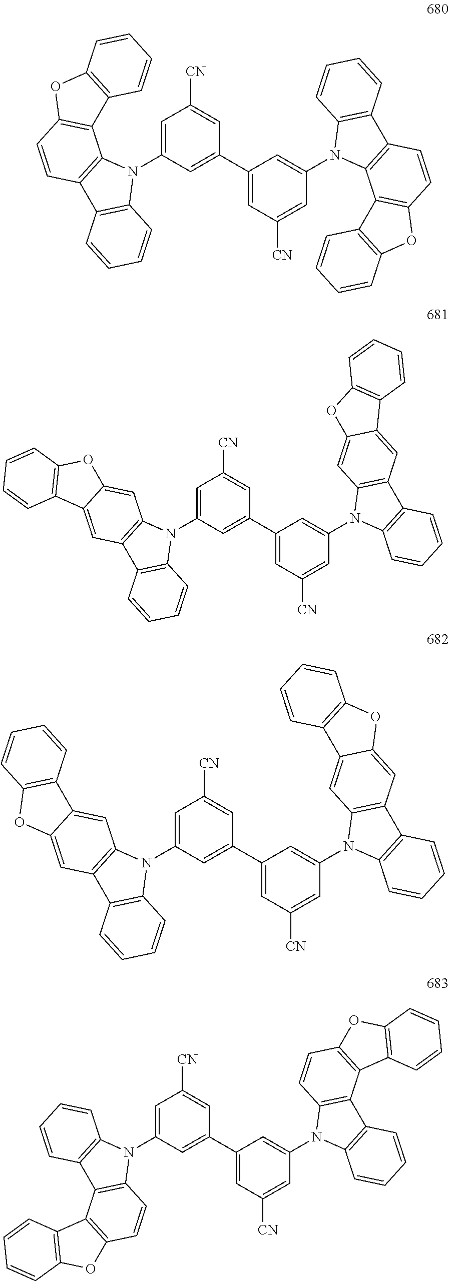 [SMILES: N#Cc1cc(-c2cc(C#N)cc(-n3c4ccccc4c4ccc5oc6ccccc6c5c43)c2)cc(-n2c3ccccc3c3ccc4oc5ccccc5c4c32)c1 ; N#Cc1cc(-c2cc(C#N)cc(-n3c4ccccc4c4cc5c(cc43)oc3ccccc35)c2)cc(-n2c3ccccc3c3cc4c(cc32)oc2ccccc24)c1 ; N#Cc1cc(-c2cc(C#N)cc(-n3c4ccccc4c4cc5oc6ccccc6c5cc43)c2)cc(-n2c3ccccc3c3cc4oc5ccccc5c4cc32)c1 ; N#Cc1cc(-c2cc(C#N)cc(-n3c4ccccc4c4c5c(ccc43)oc3ccccc35)c2)cc(-n2c3ccccc3c3c4c(ccc32)oc2ccccc24)c1]

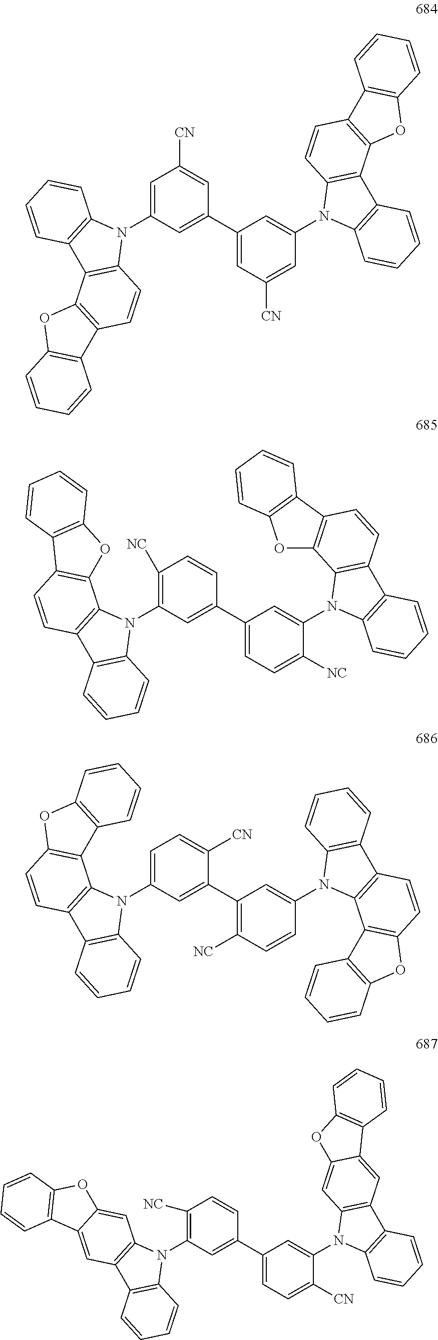

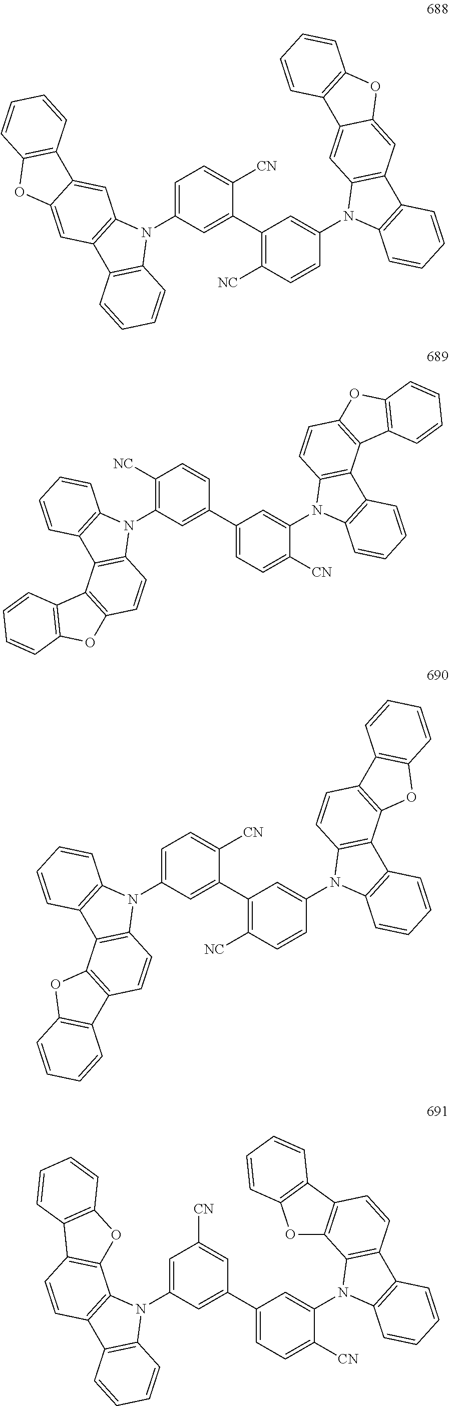 [SMILES: N#Cc1ccc(-n2c3ccccc3c3cc4oc5ccccc5c4cc32)cc1-c1cc(-n2c3ccccc3c3cc4oc5ccccc5c4cc32)ccc1C#N ; N#Cc1ccc(-c2ccc(C#N)c(-n3c4ccccc4c4c5c(ccc43)oc3ccccc35)c2)cc1-n1c2ccccc2c2c3c(ccc21)oc1ccccc13 ; N#Cc1ccc(-n2c3ccccc3c3c4oc5ccccc5c4ccc32)cc1-c1cc(-n2c3ccccc3c3c4oc5ccccc5c4ccc32)ccc1C#N ; N#Cc1cc(-c2ccc(C#N)c(-n3c4ccccc4c4ccc5c6ccccc6oc5c43)c2)cc(-n2c3ccccc3c3ccc4c5ccccc5oc4c32)c1]

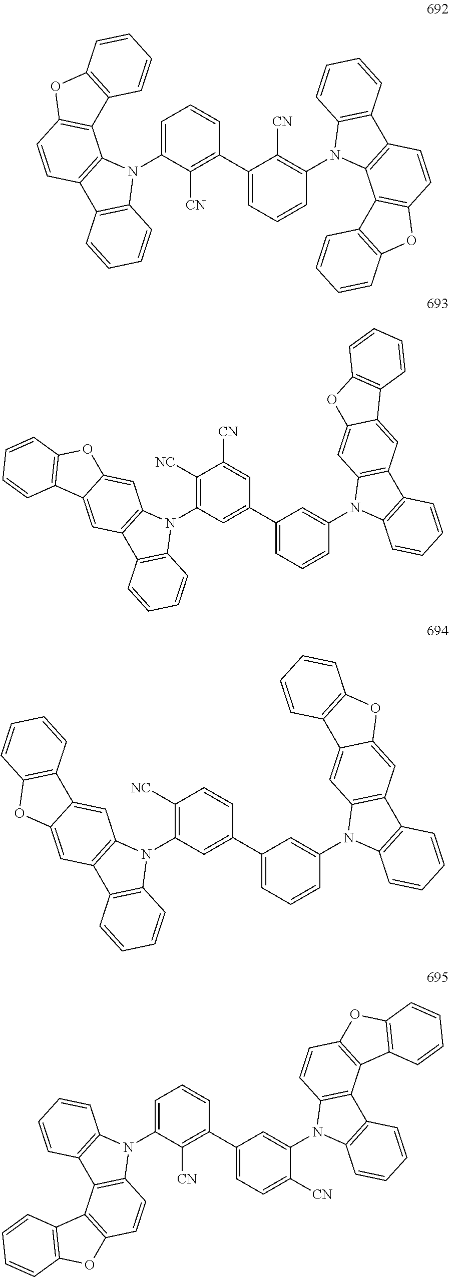

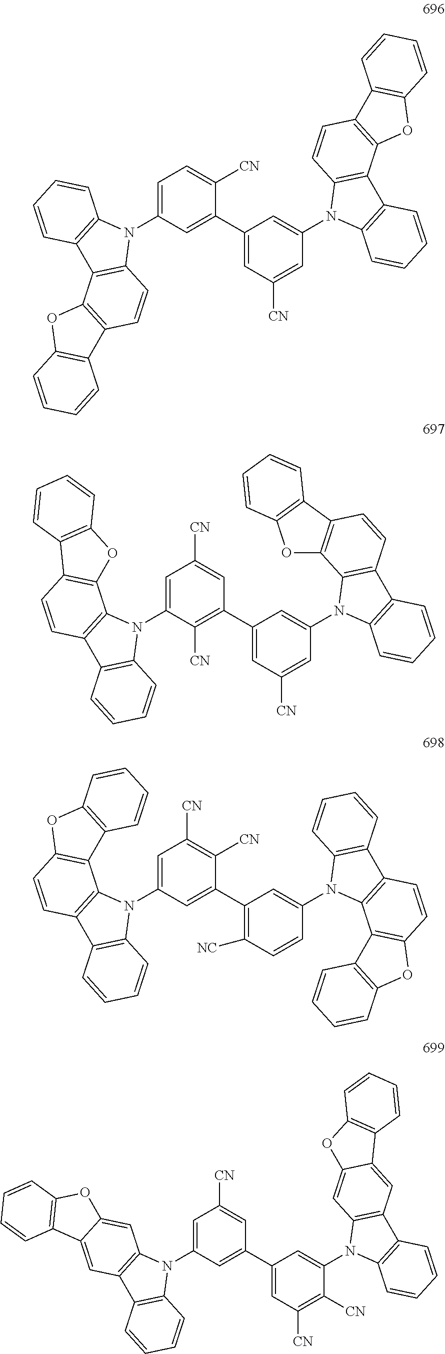

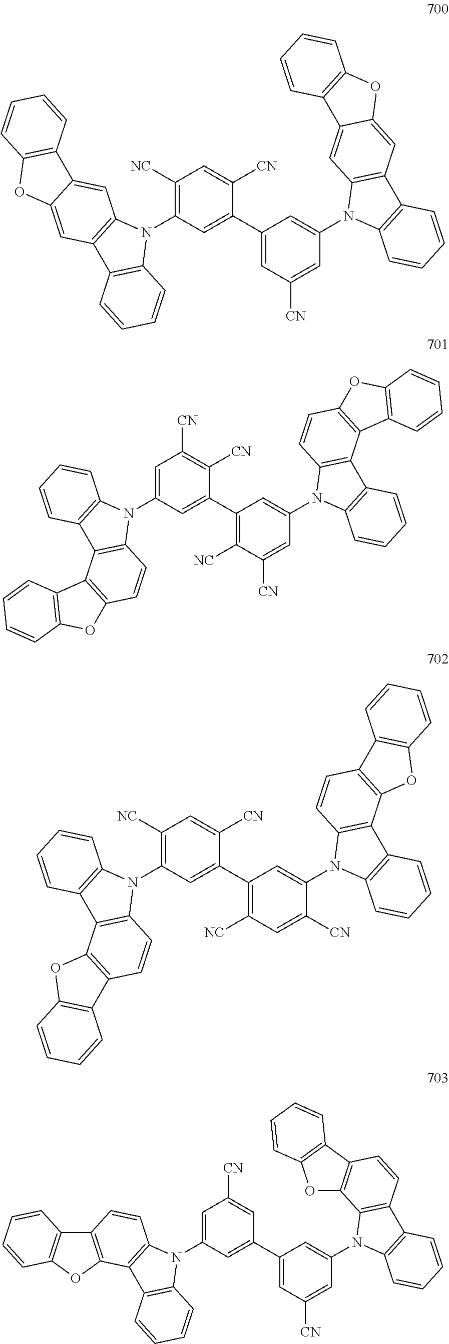 [SMILES: N#Cc1cc(-c2cc(-n3c4ccccc4c4cc5oc6ccccc6c5cc43)c(C#N)cc2C#N)cc(-n2c3ccccc3c3cc4oc5ccccc5c4cc32)c1 ; N#Cc1cc(-n2c3ccccc3c3c4c(ccc32)oc2ccccc24)cc(-c2cc(-n3c4ccccc4c4c5c(ccc43)oc3ccccc35)cc(C#N)c2C#N)c1C#N ; N#Cc1cc(C#N)c(-n2c3ccccc3c3c4oc5ccccc5c4ccc32)cc1-c1cc(-n2c3ccccc3c3c4oc5ccccc5c4ccc32)c(C#N)cc1C#N ; N#Cc1cc(-c2cc(C#N)cc(-n3c4ccccc4c4ccc5c6ccccc6oc5c43)c2)cc(-n2c3ccccc3c3c4oc5ccccc5c4ccc32)c1]

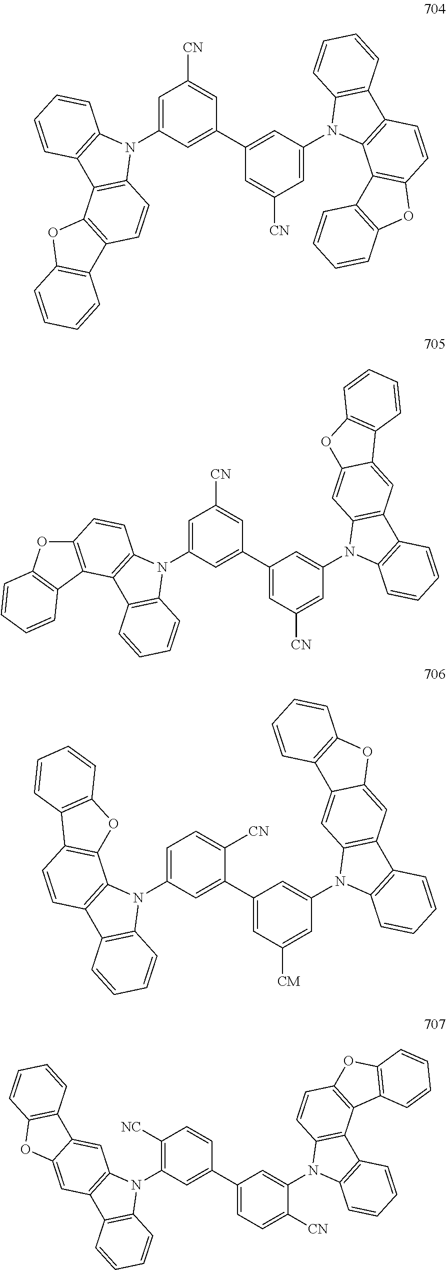

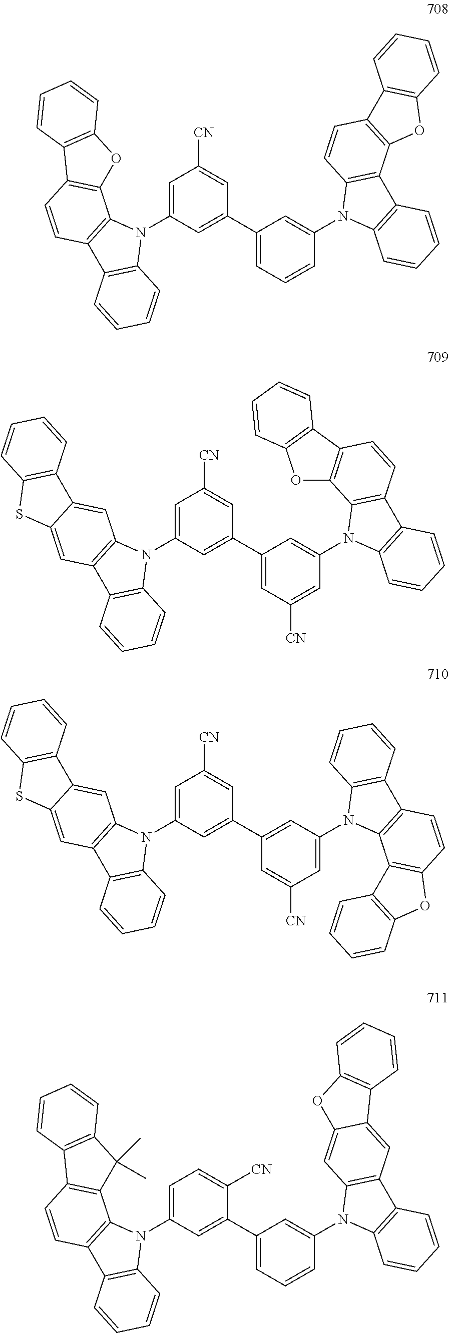 [SMILES: N#Cc1cc(-c2cccc(-n3c4ccccc4c4c5oc6ccccc6c5ccc43)c2)cc(-n2c3ccccc3c3ccc4c5ccccc5oc4c32)c1 ; N#Cc1cc(-c2cc(C#N)cc(-n3c4ccccc4c4ccc5c6ccccc6oc5c43)c2)cc(-n2c3ccccc3c3cc4sc5ccccc5c4cc32)c1 ; N#Cc1cc(-c2cc(C#N)cc(-n3c4ccccc4c4ccc5oc6ccccc6c5c43)c2)cc(-n2c3ccccc3c3cc4sc5ccccc5c4cc32)c1 ; CC1(C)c2ccccc2-c2ccc3c4ccccc4n(-c4ccc(C#N)c(-c5cccc(-n6c7ccccc7c7cc8c(cc76)oc6ccccc68)c5)c4)c3c21]

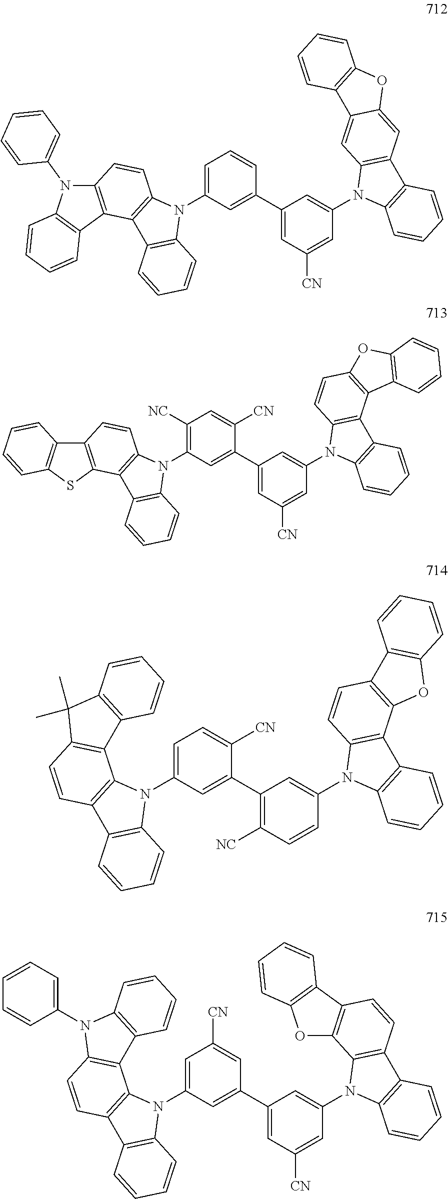 [SMILES: N#Cc1cc(-c2cccc(-n3c4ccccc4c4c5c6ccccc6n(-c6ccccc6)c5ccc43)c2)cc(-n2c3ccccc3c3cc4oc5ccccc5c4cc32)c1 ; N#Cc1cc(-c2cc(-n3c4ccccc4c4c5sc6ccccc6c5ccc43)c(C#N)cc2C#N)cc(-n2c3ccccc3c3c4c(ccc32)oc2ccccc24)c1 ; CC1(C)c2ccccc2-c2c1ccc1c3ccccc3n(-c3ccc(C#N)c(-c4cc(-n5c6ccccc6c6c7oc8ccccc8c7ccc65)ccc4C#N)c3)c21 ; N#Cc1cc(-c2cc(C#N)cc(-n3c4ccccc4c4ccc5c(c6ccccc6n5-c5ccccc5)c43)c2)cc(-n2c3ccccc3c3ccc4c5ccccc5oc4c32)c1]

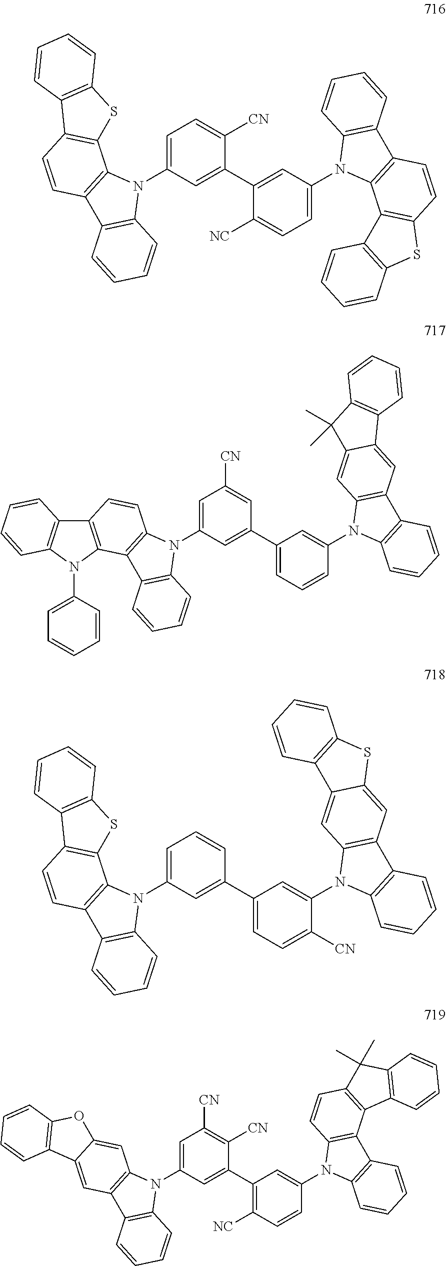 [SMILES: N#Cc1ccc(-n2c3ccccc3c3ccc4c5ccccc5sc4c32)cc1-c1cc(-n2c3ccccc3c3ccc4sc5ccccc5c4c32)ccc1C#N ; CC1(C)c2ccccc2-c2cc3c4ccccc4n(-c4cccc(-c5cc(C#N)cc(-n6c7ccccc7c7c6ccc6c8ccccc8n(-c8ccccc8)c67)c5)c4)c3cc21 ; N#Cc1ccc(-c2cccc(-n3c4ccccc4c4ccc5c6ccccc6sc5c43)c2)cc1-n1c2ccccc2c2cc3sc4ccccc4c3cc21 ; CC1(C)c2ccccc2-c2c1ccc1c2c2ccccc2n1-c1ccc(C#N)c(-c2cc(-n3c4ccccc4c4cc5c(cc43)oc3ccccc35)cc(C#N)c2C#N)c1]

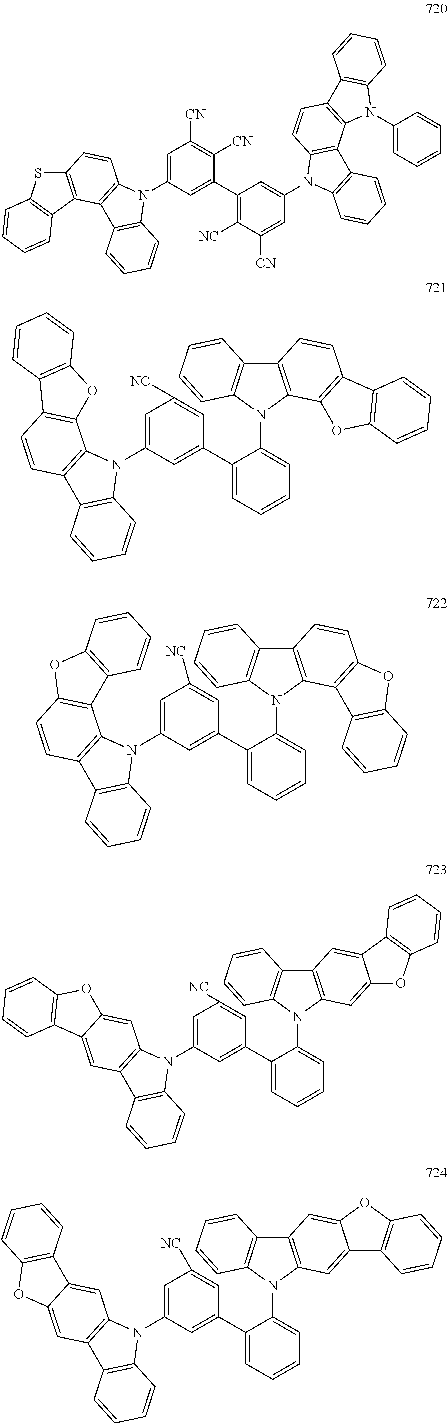

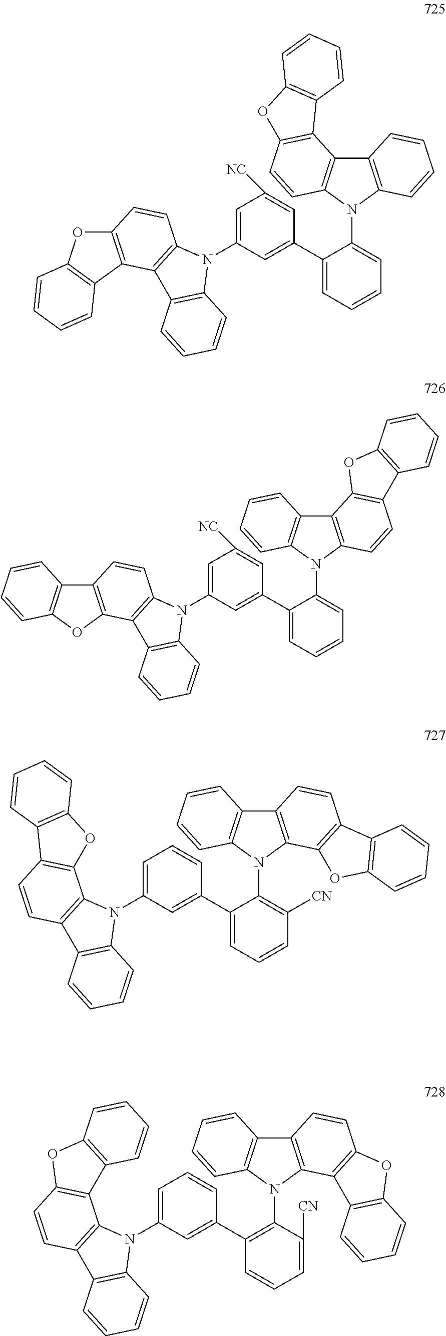 [SMILES: N#Cc1cc(-c2ccccc2-n2c3ccccc3c3c4c(ccc32)oc2ccccc24)cc(-n2c3ccccc3c3c4c(ccc32)oc2ccccc24)c1 ; N#Cc1cc(-c2ccccc2-n2c3ccccc3c3c4oc5ccccc5c4ccc32)cc(-n2c3ccccc3c3c4oc5ccccc5c4ccc32)c1 ; N#Cc1cccc(-c2cccc(-n3c4ccccc4c4ccc5c6ccccc6oc5c43)c2)c1-n1c2ccccc2c2ccc3c4ccccc4oc3c21 ; N#Cc1cccc(-c2cccc(-n3c4ccccc4c4ccc5oc6ccccc6c5c43)c2)c1-n1c2ccccc2c2ccc3oc4ccccc4c3c21]

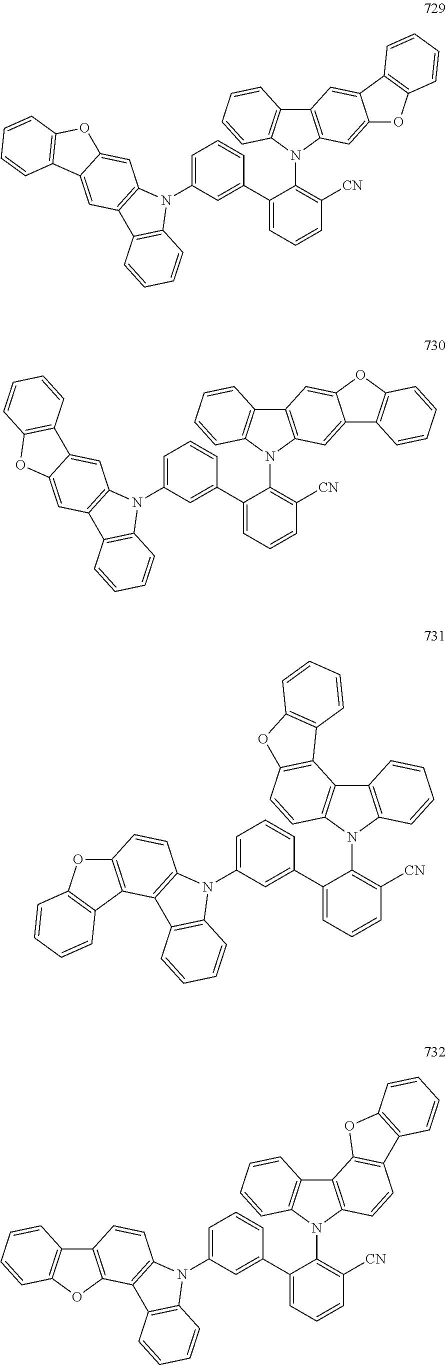 [SMILES: N#Cc1cccc(-c2cccc(-n3c4ccccc4c4cc5c(cc43)oc3ccccc35)c2)c1-n1c2ccccc2c2cc3c(cc21)oc1ccccc13 ; N#Cc1cccc(-c2cccc(-n3c4ccccc4c4cc5oc6ccccc6c5cc43)c2)c1-n1c2ccccc2c2cc3oc4ccccc4c3cc21 ; N#Cc1cccc(-c2cccc(-n3c4ccccc4c4c5c(ccc43)oc3ccccc35)c2)c1-n1c2ccccc2c2c3c(ccc21)oc1ccccc13 ; N#Cc1cccc(-c2cccc(-n3c4ccccc4c4c5oc6ccccc6c5ccc43)c2)c1-n1c2ccccc2c2c3oc4ccccc4c3ccc21]

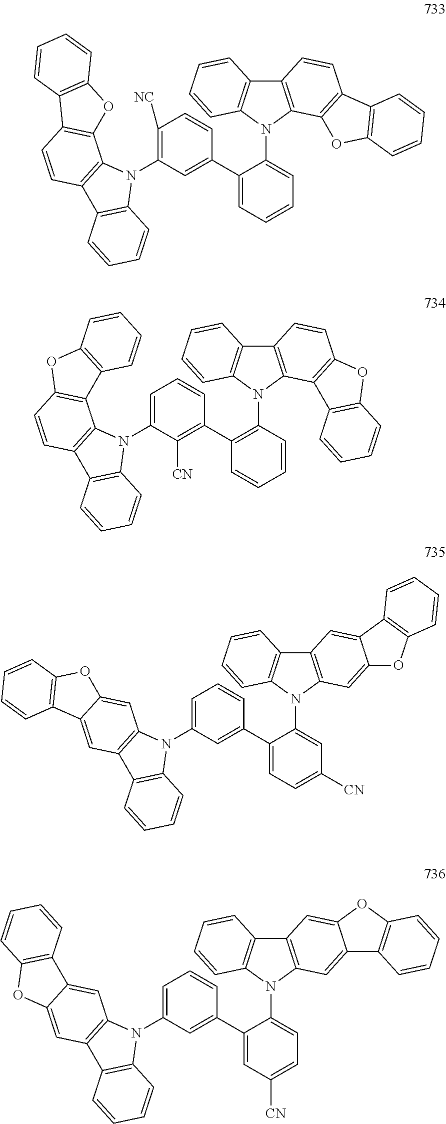 [SMILES: N#Cc1ccc(-c2ccccc2-n2c3ccccc3c3ccc4c5ccccc5oc4c32)cc1-n1c2ccccc2c2ccc3c4ccccc4oc3c21 ; N#Cc1c(-c2ccccc2-n2c3ccccc3c3ccc4oc5ccccc5c4c32)cccc1-n1c2ccccc2c2ccc3oc4ccccc4c3c21 ; N#Cc1ccc(-c2cccc(-n3c4ccccc4c4cc5c(cc43)oc3ccccc35)c2)c(-n2c3ccccc3c3cc4c(cc32)oc2ccccc24)c1 ; N#Cc1ccc(-n2c3ccccc3c3cc4oc5ccccc5c4cc32)c(-c2cccc(-n3c4ccccc4c4cc5oc6ccccc6c5cc43)c2)c1]

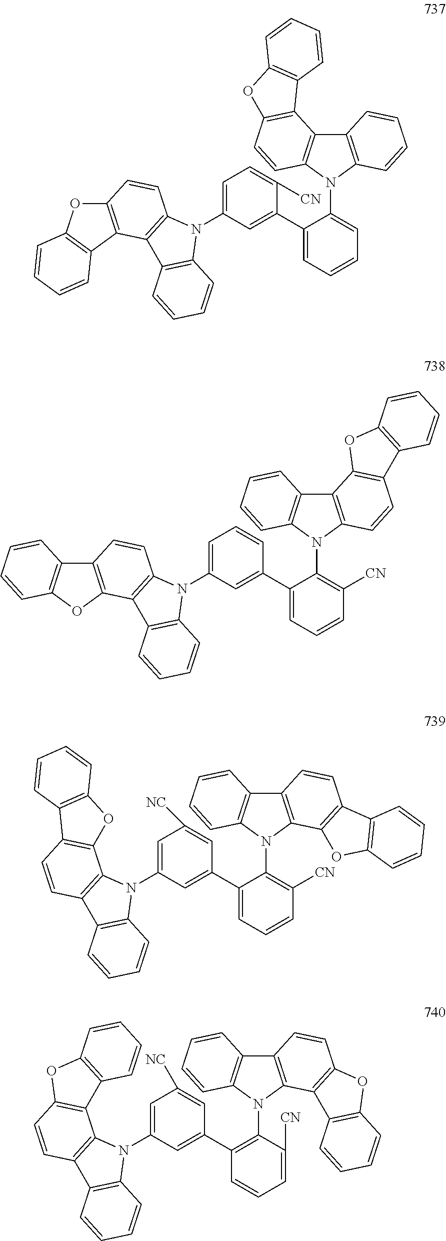 [SMILES: N#Cc1ccc(-n2c3ccccc3c3c4c(ccc32)oc2ccccc24)cc1-c1ccccc1-n1c2ccccc2c2c3c(ccc21)oc1ccccc13 ; N#Cc1cccc(-c2cccc(-n3c4ccccc4c4c5oc6ccccc6c5ccc43)c2)c1-n1c2ccccc2c2c3oc4ccccc4c3ccc21 ; N#Cc1cc(-c2cccc(C#N)c2-n2c3ccccc3c3ccc4c5ccccc5oc4c32)cc(-n2c3ccccc3c3ccc4c5ccccc5oc4c32)c1 ; N#Cc1cc(-c2cccc(C#N)c2-n2c3ccccc3c3ccc4oc5ccccc5c4c32)cc(-n2c3ccccc3c3ccc4oc5ccccc5c4c32)c1]

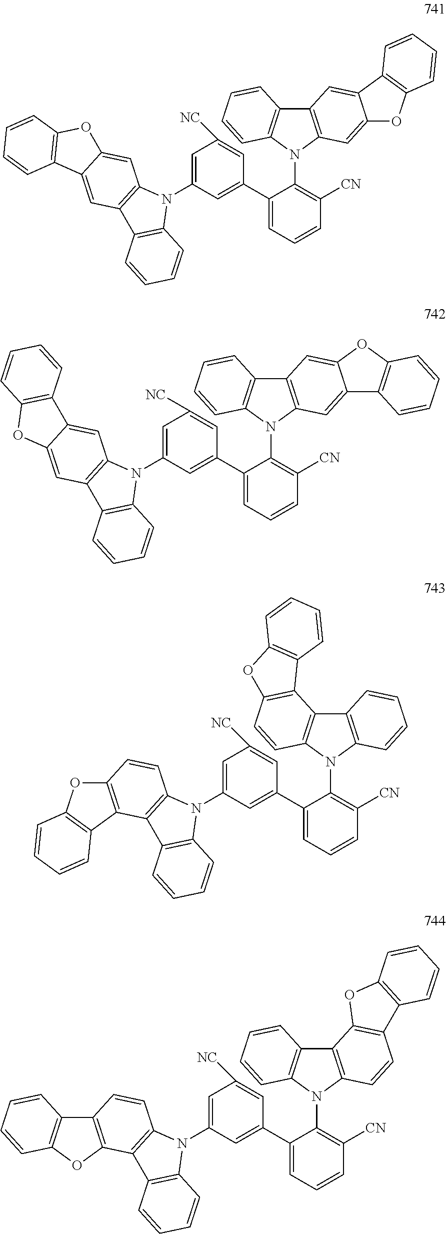 [SMILES: N#Cc1cc(-c2cccc(C#N)c2-n2c3ccccc3c3cc4c(cc32)oc2ccccc24)cc(-n2c3ccccc3c3cc4c(cc32)oc2ccccc24)c1 ; N#Cc1cc(-c2cccc(C#N)c2-n2c3ccccc3c3cc4oc5ccccc5c4cc32)cc(-n2c3ccccc3c3cc4oc5ccccc5c4cc32)c1 ; N#Cc1cc(-c2cccc(C#N)c2-n2c3ccccc3c3c4c(ccc32)oc2ccccc24)cc(-n2c3ccccc3c3c4c(ccc32)oc2ccccc24)c1 ; N#Cc1cc(-c2cccc(C#N)c2-n2c3ccccc3c3c4oc5ccccc5c4ccc32)cc(-n2c3ccccc3c3c4oc5ccccc5c4ccc32)c1]

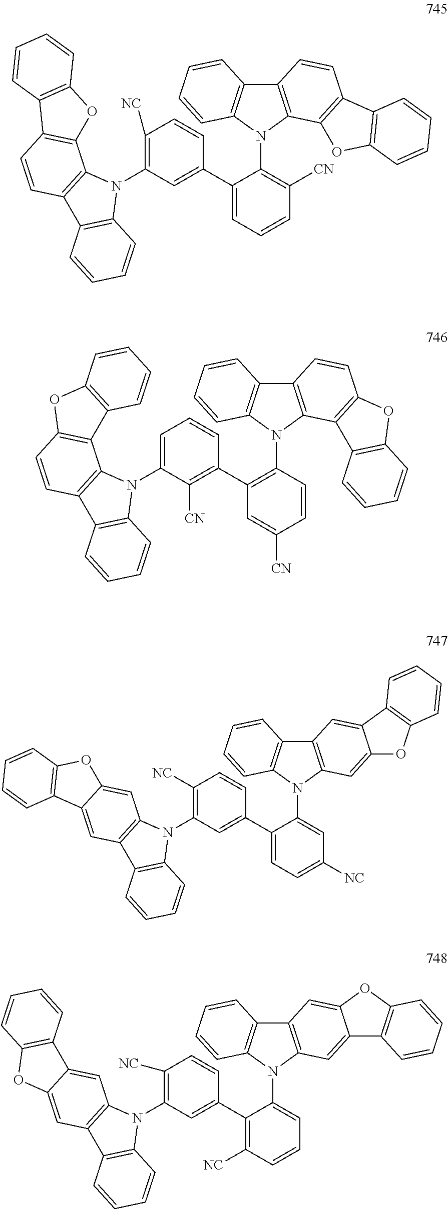

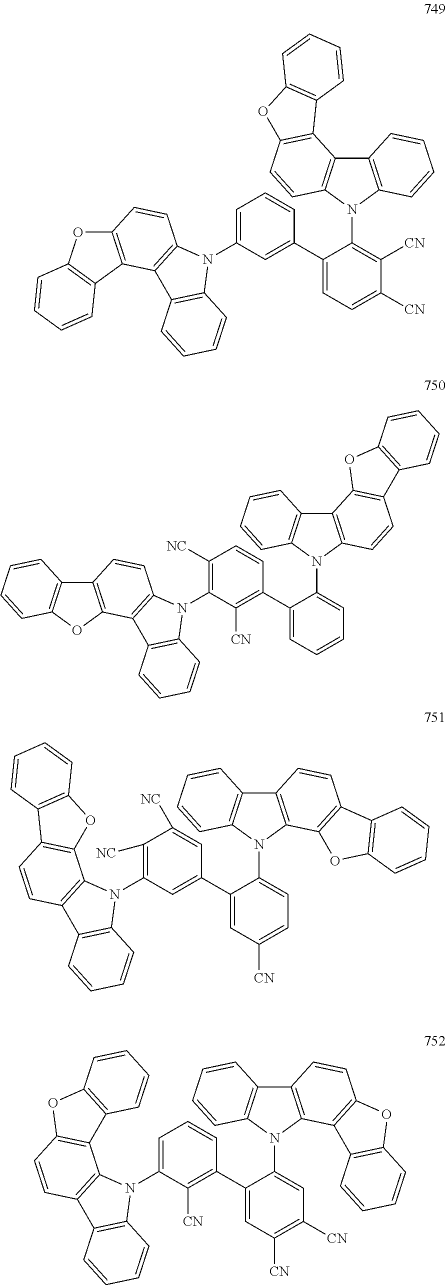 [SMILES: N#Cc1ccc(-c2cccc(-n3c4ccccc4c4c5c(ccc43)oc3ccccc35)c2)c(-n2c3ccccc3c3c4c(ccc32)oc2ccccc24)c1C#N ; N#Cc1ccc(-c2ccccc2-n2c3ccccc3c3c4oc5ccccc5c4ccc32)c(C#N)c1-n1c2ccccc2c2c3oc4ccccc4c3ccc21 ; N#Cc1ccc(-n2c3ccccc3c3ccc4c5ccccc5oc4c32)c(-c2cc(C#N)c(C#N)c(-n3c4ccccc4c4ccc5c6ccccc6oc5c43)c2)c1 ; N#Cc1cc(-c2cccc(-n3c4ccccc4c4ccc5oc6ccccc6c5c43)c2C#N)c(-n2c3ccccc3c3ccc4oc5ccccc5c4c32)cc1C#N]

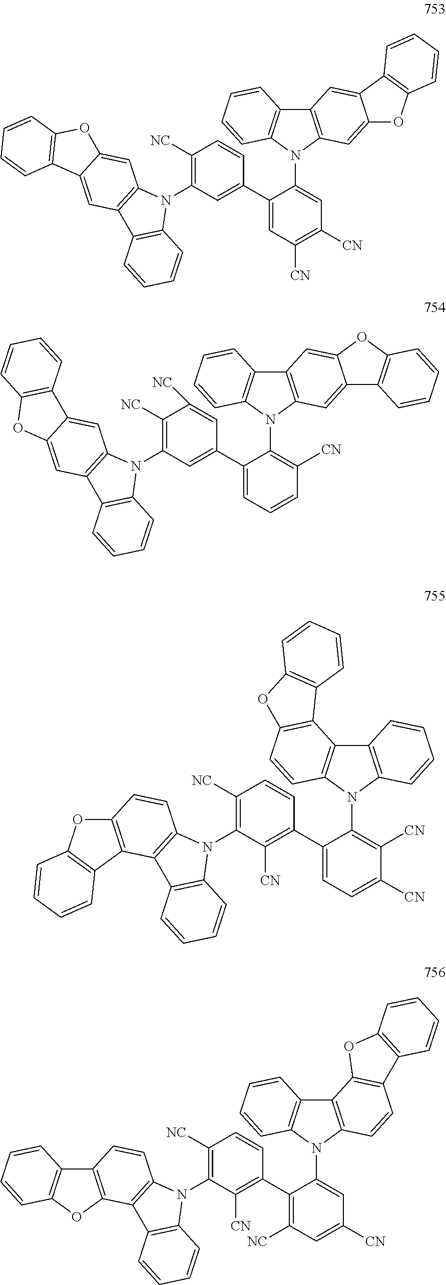 [SMILES: N#Cc1cc(-c2ccc(C#N)c(-n3c4ccccc4c4cc5c(cc43)oc3ccccc35)c2)c(-n2c3ccccc3c3cc4c(cc32)oc2ccccc24)cc1C#N ; N#Cc1cc(-c2cccc(C#N)c2-n2c3ccccc3c3cc4oc5ccccc5c4cc32)cc(-n2c3ccccc3c3cc4oc5ccccc5c4cc32)c1C#N ; N#Cc1ccc(-c2ccc(C#N)c(-n3c4ccccc4c4c5c(ccc43)oc3ccccc35)c2C#N)c(-n2c3ccccc3c3c4c(ccc32)oc2ccccc24)c1C#N ; N#Cc1cc(C#N)c(-c2ccc(C#N)c(-n3c4ccccc4c4c5oc6ccccc6c5ccc43)c2C#N)c(-n2c3ccccc3c3c4oc5ccccc5c4ccc32)c1]

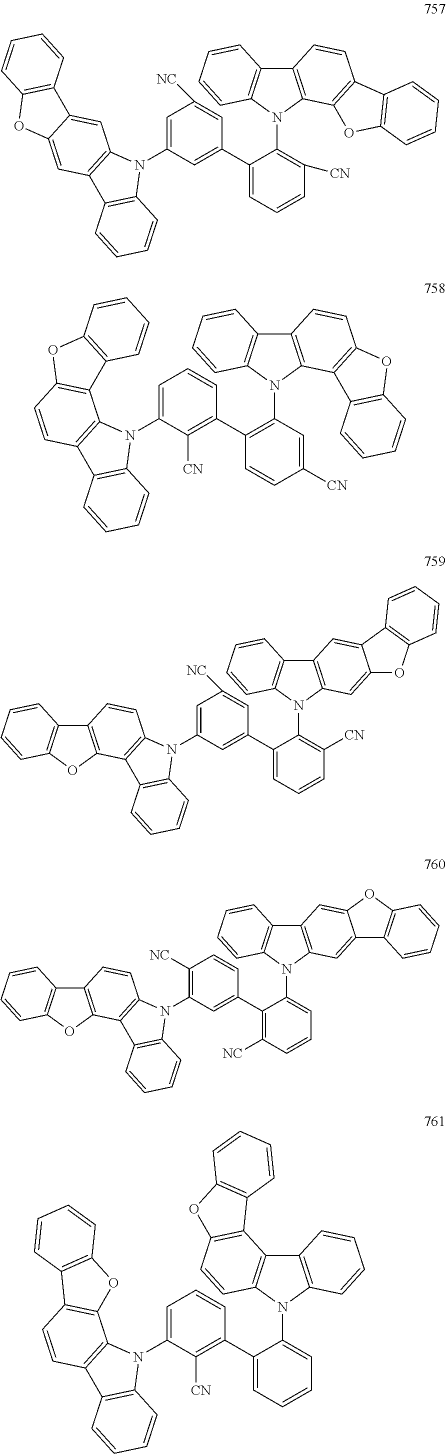

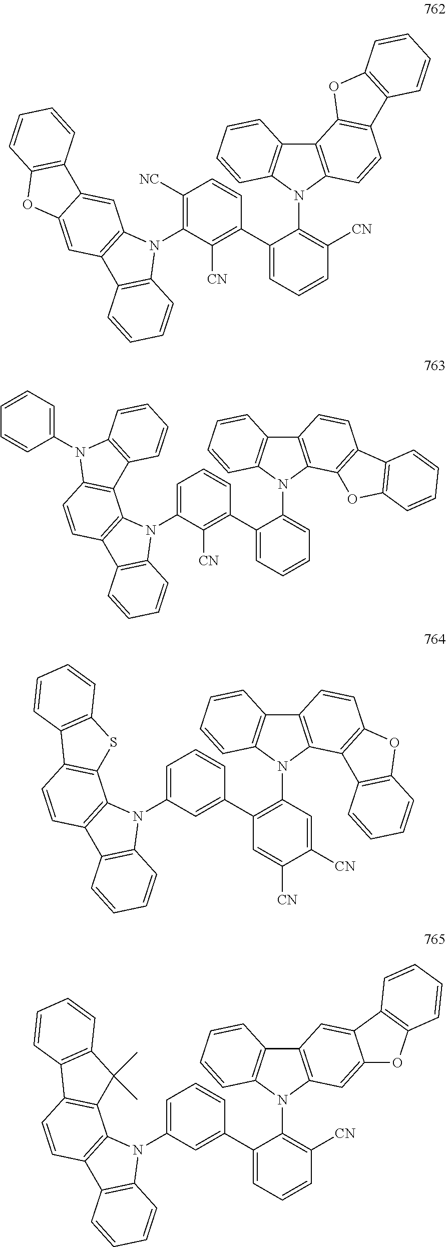 [SMILES: N#Cc1ccc(-c2cccc(C#N)c2-n2c3ccccc3c3c4oc5ccccc5c4ccc32)c(C#N)c1-n1c2ccccc2c2cc3oc4ccccc4c3cc21 ; N#Cc1c(-c2ccccc2-n2c3ccccc3c3ccc4c5ccccc5oc4c32)cccc1-n1c2ccccc2c2ccc3c(c4ccccc4n3-c3ccccc3)c21 ; N#Cc1cc(-c2cccc(-n3c4ccccc4c4ccc5c6ccccc6sc5c43)c2)c(-n2c3ccccc3c3ccc4oc5ccccc5c4c32)cc1C#N ; CC1(C)c2ccccc2-c2ccc3c4ccccc4n(-c4cccc(-c5cccc(C#N)c5-n5c6ccccc6c6cc7c(cc65)oc5ccccc57)c4)c3c21]

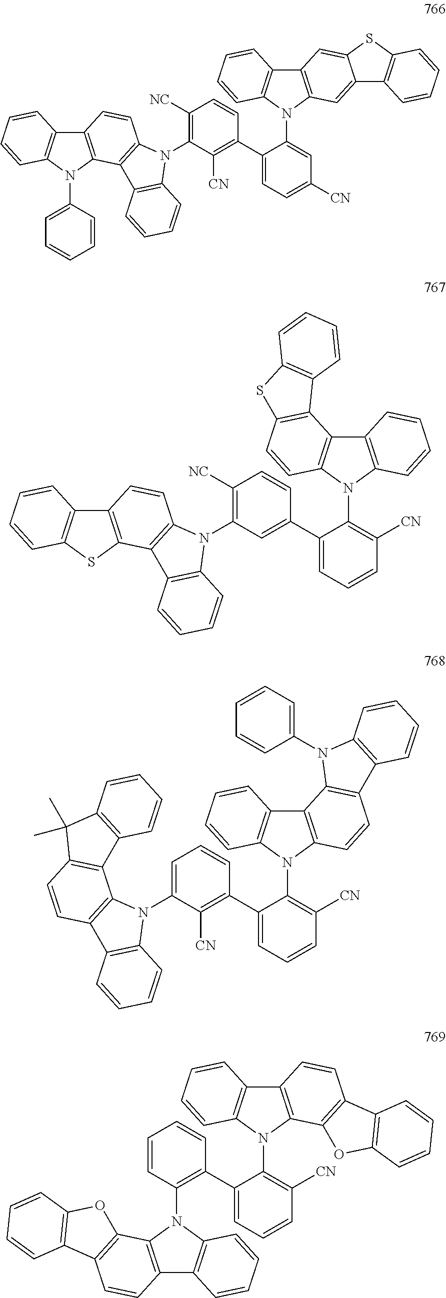 [SMILES: N#Cc1ccc(-c2ccc(C#N)c(-n3c4ccccc4c4c3ccc3c5ccccc5n(-c5ccccc5)c34)c2C#N)c(-n2c3ccccc3c3cc4sc5ccccc5c4cc32)c1 ; N#Cc1ccc(-c2cccc(C#N)c2-n2c3ccccc3c3c4c(ccc32)sc2ccccc24)cc1-n1c2ccccc2c2c3sc4ccccc4c3ccc21 ; CC1(C)c2ccccc2-c2c1ccc1c3ccccc3n(-c3cccc(-c4cccc(C#N)c4-n4c5ccccc5c5c4ccc4c6ccccc6n(-c6ccccc6)c45)c3C#N)c21 ; N#Cc1cccc(-c2ccccc2-n2c3ccccc3c3ccc4c5ccccc5oc4c32)c1-n1c2ccccc2c2ccc3c4ccccc4oc3c21]

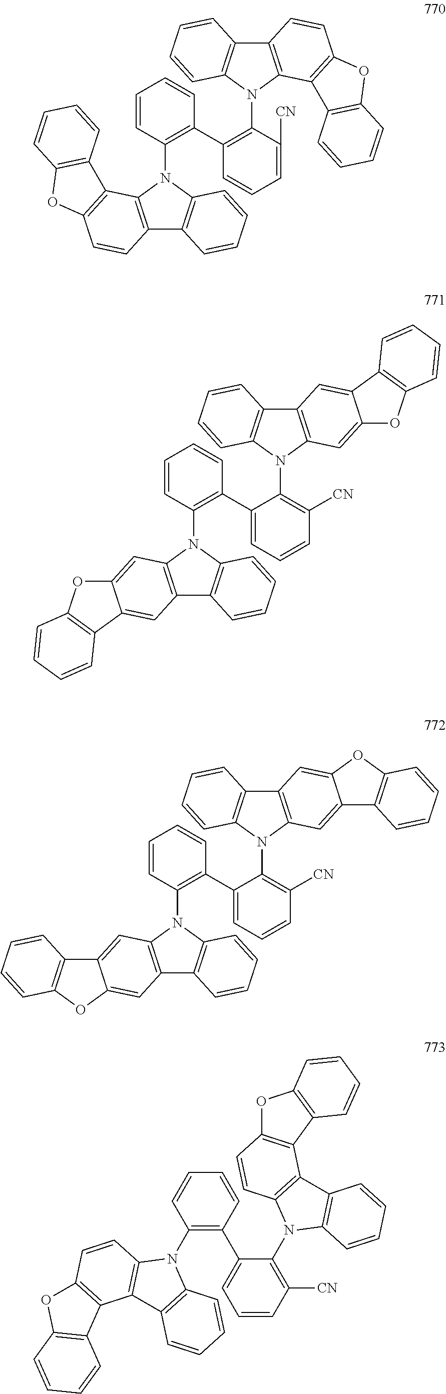 [SMILES: N#Cc1cccc(-c2ccccc2-n2c3ccccc3c3ccc4oc5ccccc5c4c32)c1-n1c2ccccc2c2ccc3oc4ccccc4c3c21 ; N#Cc1cccc(-c2ccccc2-n2c3ccccc3c3cc4c(cc32)oc2ccccc24)c1-n1c2ccccc2c2cc3c(cc21)oc1ccccc13 ; N#Cc1cccc(-c2ccccc2-n2c3ccccc3c3cc4oc5ccccc5c4cc32)c1-n1c2ccccc2c2cc3oc4ccccc4c3cc21 ; N#Cc1cccc(-c2ccccc2-n2c3ccccc3c3c4c(ccc32)oc2ccccc24)c1-n1c2ccccc2c2c3c(ccc21)oc1ccccc13]

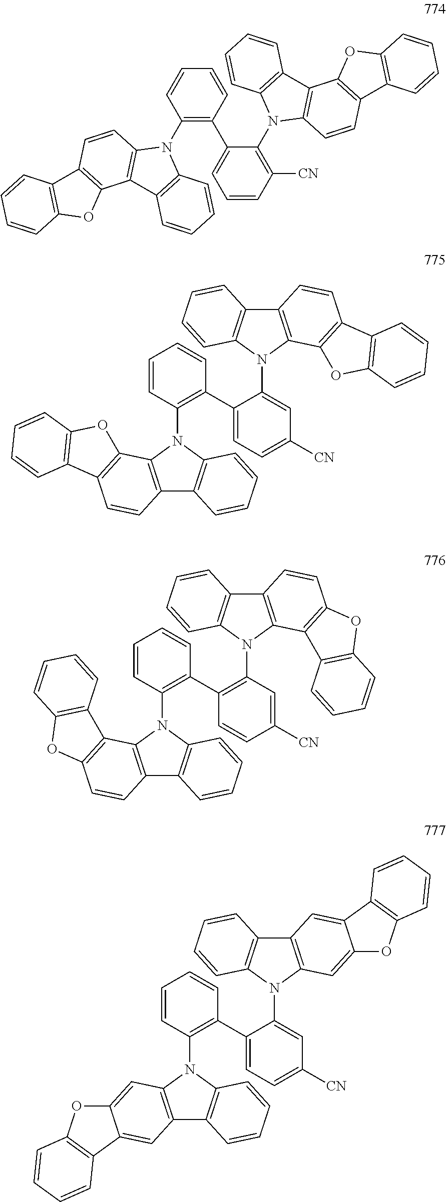 [SMILES: N#Cc1cccc(-c2ccccc2-n2c3ccccc3c3c4oc5ccccc5c4ccc32)c1-n1c2ccccc2c2c3oc4ccccc4c3ccc21 ; N#Cc1ccc(-c2ccccc2-n2c3ccccc3c3ccc4c5ccccc5oc4c32)c(-n2c3ccccc3c3ccc4c5ccccc5oc4c32)c1 ; N#Cc1ccc(-c2ccccc2-n2c3ccccc3c3ccc4oc5ccccc5c4c32)c(-n2c3ccccc3c3ccc4oc5ccccc5c4c32)c1 ; N#Cc1ccc(-c2ccccc2-n2c3ccccc3c3cc4c(cc32)oc2ccccc24)c(-n2c3ccccc3c3cc4c(cc32)oc2ccccc24)c1]

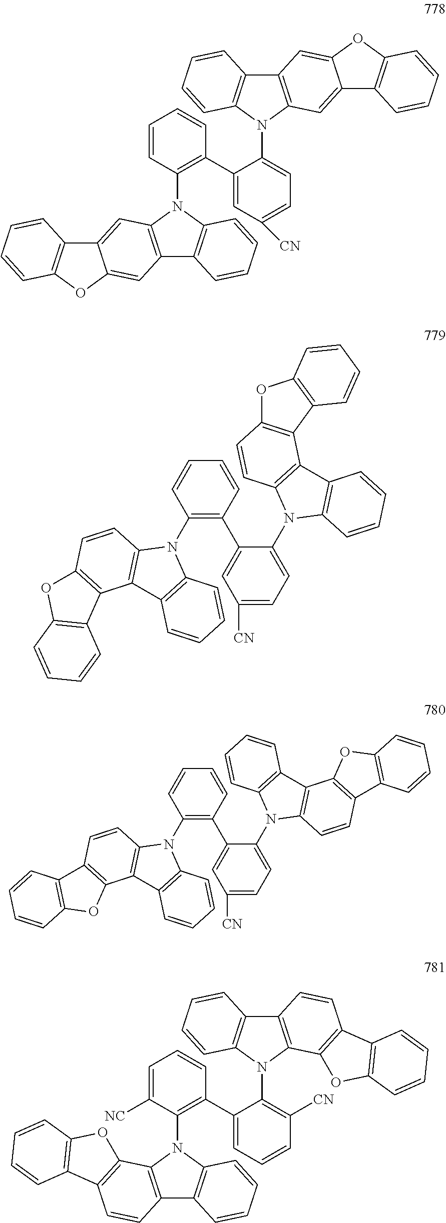 [SMILES: N#Cc1ccc(-n2c3ccccc3c3cc4oc5ccccc5c4cc32)c(-c2ccccc2-n2c3ccccc3c3cc4oc5ccccc5c4cc32)c1 ; N#Cc1ccc(-n2c3ccccc3c3c4c(ccc32)oc2ccccc24)c(-c2ccccc2-n2c3ccccc3c3c4c(ccc32)oc2ccccc24)c1 ; N#Cc1ccc(-n2c3ccccc3c3c4oc5ccccc5c4ccc32)c(-c2ccccc2-n2c3ccccc3c3c4oc5ccccc5c4ccc32)c1 ; N#Cc1cccc(-c2cccc(C#N)c2-n2c3ccccc3c3ccc4c5ccccc5oc4c32)c1-n1c2ccccc2c2ccc3c4ccccc4oc3c21]

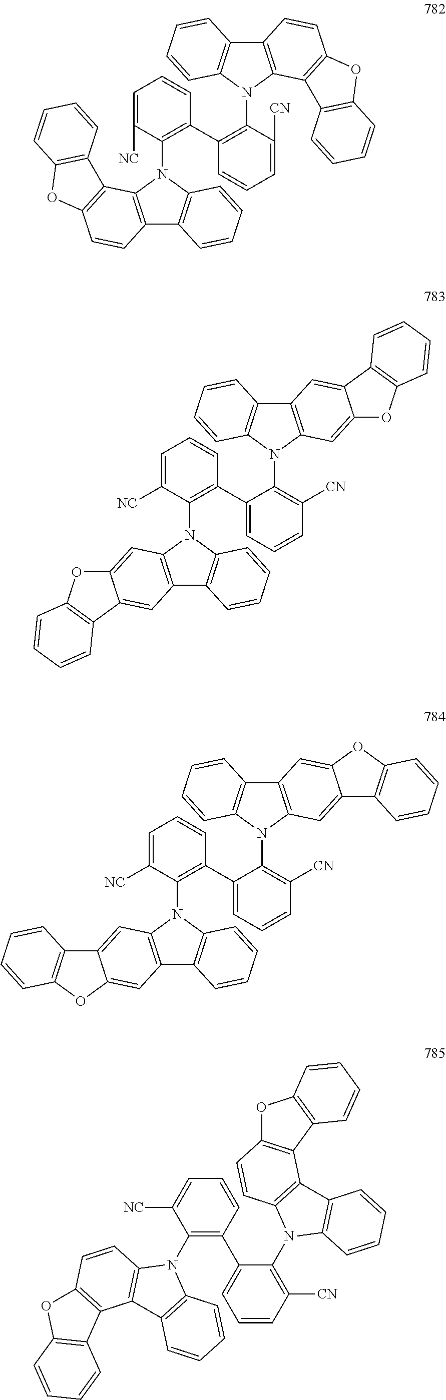 [SMILES: N#Cc1cccc(-c2cccc(C#N)c2-n2c3ccccc3c3ccc4oc5ccccc5c4c32)c1-n1c2ccccc2c2ccc3oc4ccccc4c3c21 ; N#Cc1cccc(-c2cccc(C#N)c2-n2c3ccccc3c3cc4c(cc32)oc2ccccc24)c1-n1c2ccccc2c2cc3c(cc21)oc1ccccc13 ; N#Cc1cccc(-c2cccc(C#N)c2-n2c3ccccc3c3cc4oc5ccccc5c4cc32)c1-n1c2ccccc2c2cc3oc4ccccc4c3cc21 ; N#Cc1cccc(-c2cccc(C#N)c2-n2c3ccccc3c3c4c(ccc32)oc2ccccc24)c1-n1c2ccccc2c2c3c(ccc21)oc1ccccc13]

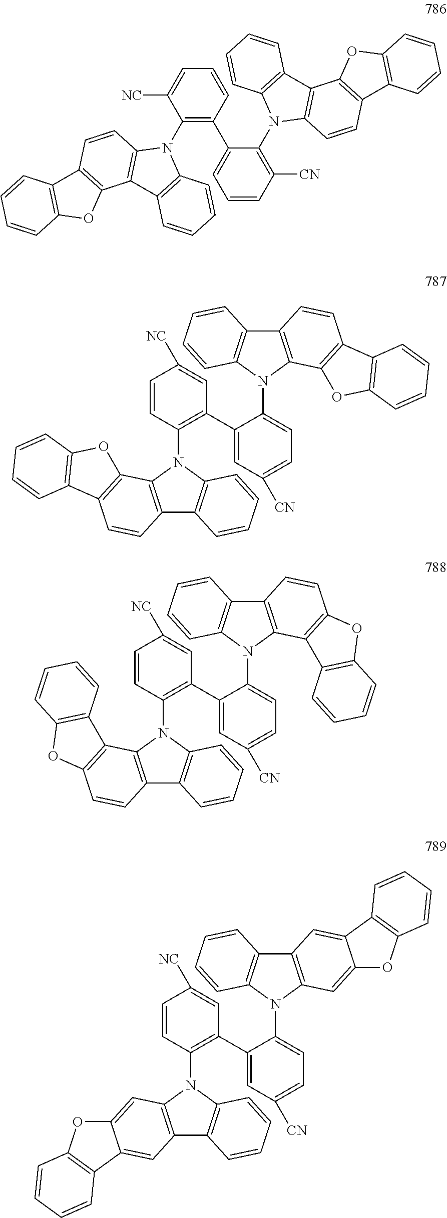

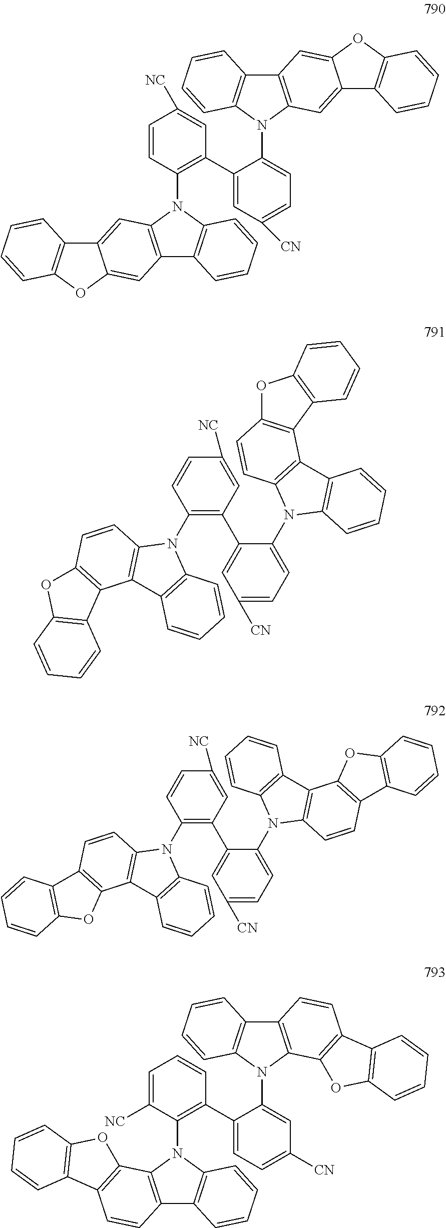 [SMILES: N#Cc1ccc(-n2c3ccccc3c3cc4oc5ccccc5c4cc32)c(-c2cc(C#N)ccc2-n2c3ccccc3c3cc4oc5ccccc5c4cc32)c1 ; N#Cc1ccc(-n2c3ccccc3c3c4c(ccc32)oc2ccccc24)c(-c2cc(C#N)ccc2-n2c3ccccc3c3c4c(ccc32)oc2ccccc24)c1 ; N#Cc1ccc(-n2c3ccccc3c3c4oc5ccccc5c4ccc32)c(-c2cc(C#N)ccc2-n2c3ccccc3c3c4oc5ccccc5c4ccc32)c1 ; N#Cc1ccc(-c2cccc(C#N)c2-n2c3ccccc3c3ccc4c5ccccc5oc4c32)c(-n2c3ccccc3c3ccc4c5ccccc5oc4c32)c1]

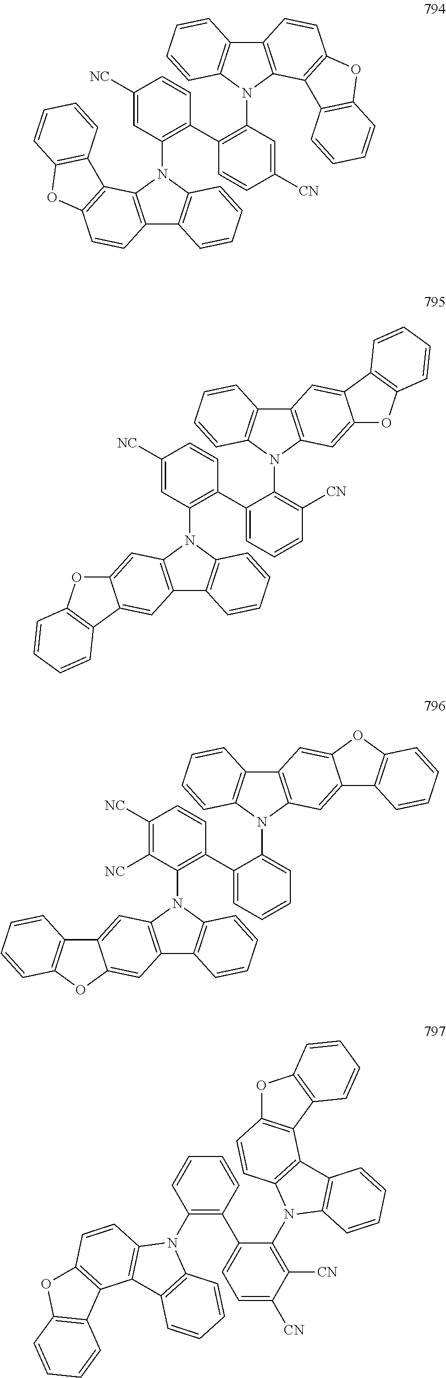 [SMILES: N#Cc1ccc(-c2ccc(C#N)cc2-n2c3ccccc3c3ccc4oc5ccccc5c4c32)c(-n2c3ccccc3c3ccc4oc5ccccc5c4c32)c1 ; N#Cc1ccc(-c2cccc(C#N)c2-n2c3ccccc3c3cc4c(cc32)oc2ccccc24)c(-n2c3ccccc3c3cc4c(cc32)oc2ccccc24)c1 ; N#Cc1ccc(-c2ccccc2-n2c3ccccc3c3cc4oc5ccccc5c4cc32)c(-n2c3ccccc3c3cc4oc5ccccc5c4cc32)c1C#N ; N#Cc1ccc(-c2ccccc2-n2c3ccccc3c3c4c(ccc32)oc2ccccc24)c(-n2c3ccccc3c3c4c(ccc32)oc2ccccc24)c1C#N]

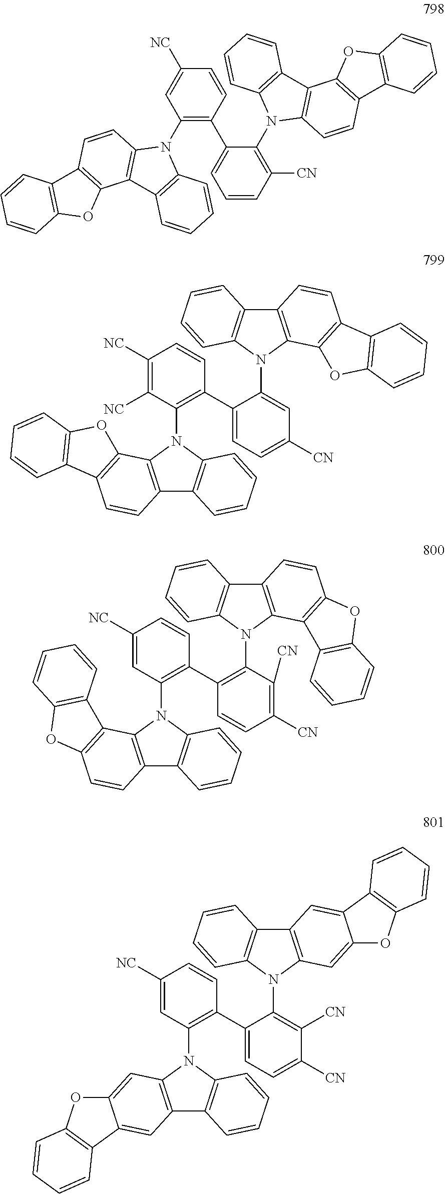

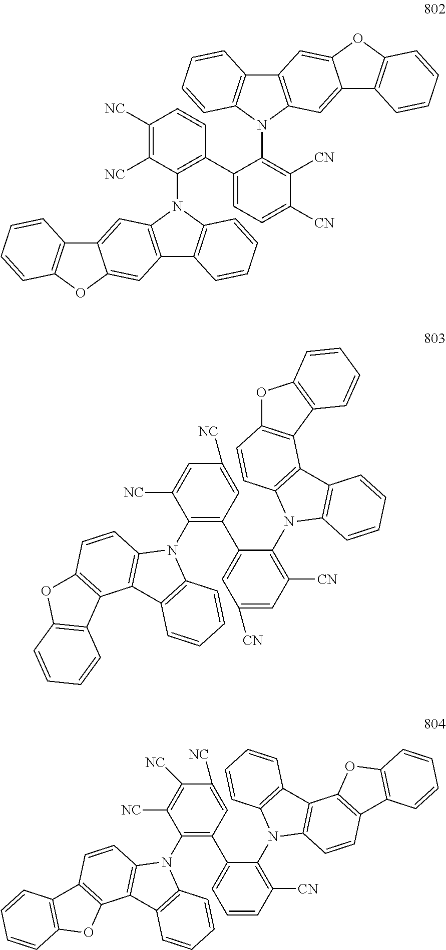 [SMILES: N#Cc1ccc(-c2ccc(C#N)c(C#N)c2-n2c3ccccc3c3cc4oc5ccccc5c4cc32)c(-n2c3ccccc3c3cc4oc5ccccc5c4cc32)c1C#N ; N#Cc1cc(C#N)c(-n2c3ccccc3c3c4c(ccc32)oc2ccccc24)c(-c2cc(C#N)cc(C#N)c2-n2c3ccccc3c3c4c(ccc32)oc2ccccc24)c1 ; N#Cc1cc(-c2cccc(C#N)c2-n2c3ccccc3c3c4oc5ccccc5c4ccc32)c(-n2c3ccccc3c3c4oc5ccccc5c4ccc32)c(C#N)c1C#N]

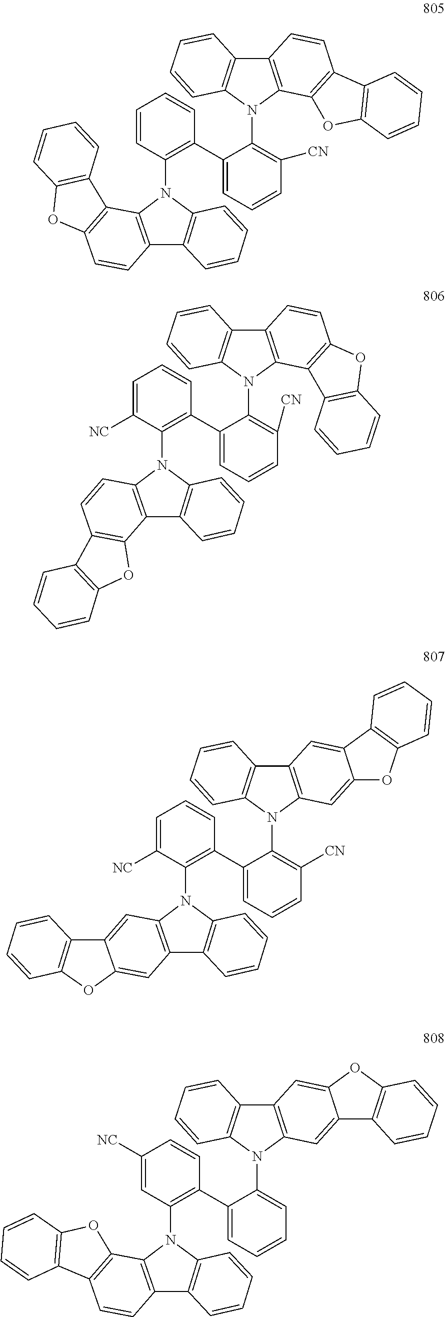

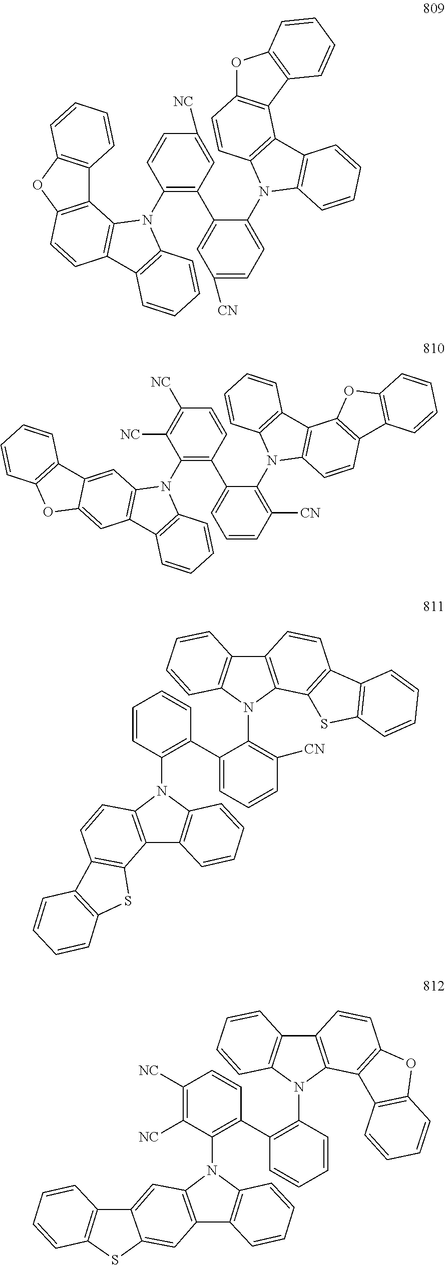 [SMILES: N#Cc1ccc(-n2c3ccccc3c3c4c(ccc32)oc2ccccc24)c(-c2cc(C#N)ccc2-n2c3ccccc3c3ccc4oc5ccccc5c4c32)c1 ; N#Cc1ccc(-c2cccc(C#N)c2-n2c3ccccc3c3c4oc5ccccc5c4ccc32)c(-n2c3ccccc3c3cc4oc5ccccc5c4cc32)c1C#N ; N#Cc1cccc(-c2ccccc2-n2c3ccccc3c3c4sc5ccccc5c4ccc32)c1-n1c2ccccc2c2ccc3c4ccccc4sc3c21 ; N#Cc1ccc(-c2ccccc2-n2c3ccccc3c3ccc4oc5ccccc5c4c32)c(-n2c3ccccc3c3cc4sc5ccccc5c4cc32)c1C#N]

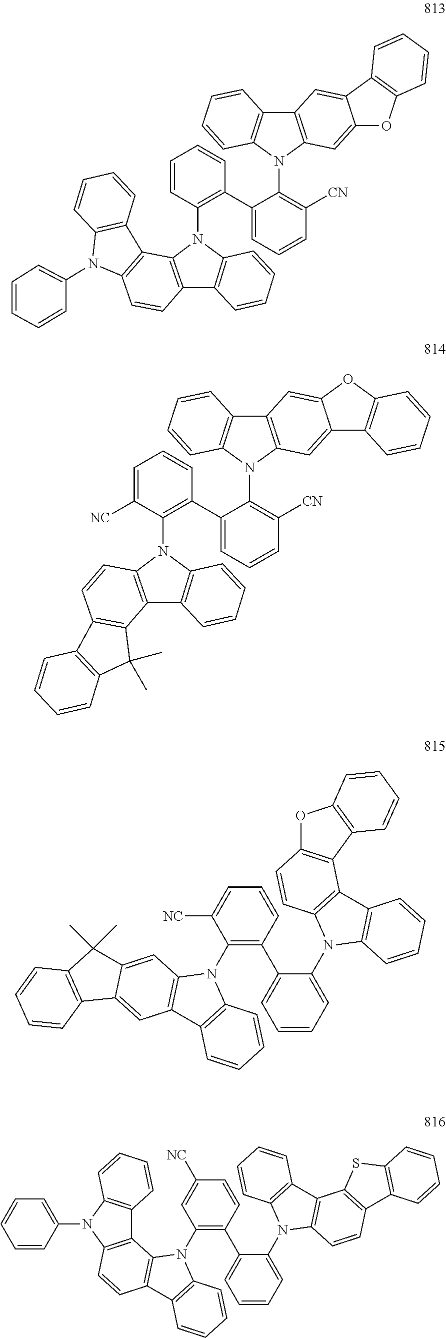 [SMILES: N#Cc1cccc(-c2ccccc2-n2c3ccccc3c3ccc4c(c5ccccc5n4-c4ccccc4)c32)c1-n1c2ccccc2c2cc3c(cc21)oc1ccccc13 ; CC1(C)c2ccccc2-c2ccc3c(c21)c1ccccc1n3-c1c(C#N)cccc1-c1cccc(C#N)c1-n1c2ccccc2c2cc3oc4ccccc4c3cc21 ; CC1(C)c2ccccc2-c2cc3c4ccccc4n(-c4c(C#N)cccc4-c4ccccc4-n4c5ccccc5c5c6c(ccc54)oc4ccccc46)c3cc21 ; N#Cc1ccc(-c2ccccc2-n2c3ccccc3c3c4sc5ccccc5c4ccc32)c(-n2c3ccccc3c3ccc4c(c5ccccc5n4-c4ccccc4)c32)c1]

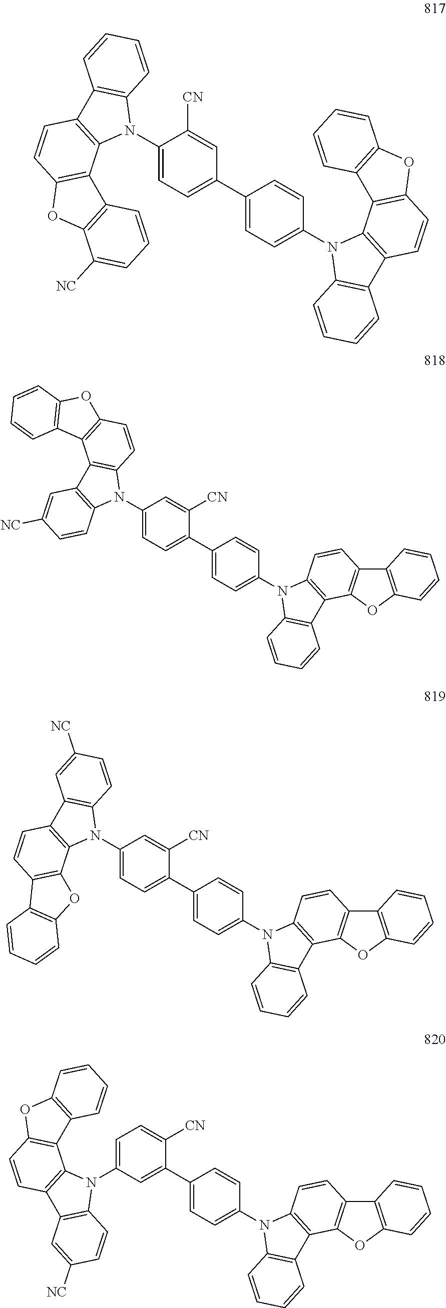 [SMILES: N#Cc1cc(-c2ccc(-n3c4ccccc4c4ccc5oc6ccccc6c5c43)cc2)ccc1-n1c2ccccc2c2ccc3oc4c(C#N)cccc4c3c21 ; N#Cc1ccc2c(c1)c1c3c(ccc1n2-c1ccc(-c2ccc(-n4c5ccccc5c5c6oc7ccccc7c6ccc54)cc2)c(C#N)c1)oc1ccccc13 ; N#Cc1ccc2c(c1)c1ccc3c4ccccc4oc3c1n2-c1ccc(-c2ccc(-n3c4ccccc4c4c5oc6ccccc6c5ccc43)cc2)c(C#N)c1 ; N#Cc1ccc2c(c1)c1ccc3oc4ccccc4c3c1n2-c1ccc(C#N)c(-c2ccc(-n3c4ccccc4c4c5oc6ccccc6c5ccc43)cc2)c1]

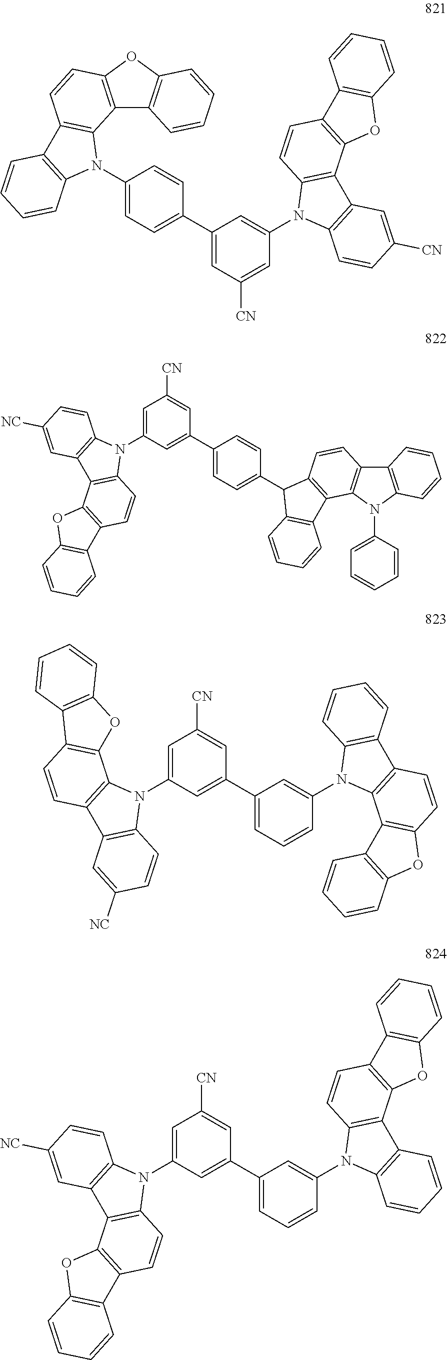 [SMILES: N#Cc1cc(-c2ccc(-n3c4ccccc4c4ccc5oc6ccccc6c5c43)cc2)cc(-n2c3ccc(C#N)cc3c3c4oc5ccccc5c4ccc32)c1 ; N#Cc1cc(-c2ccc(C3c4ccccc4-c4c3ccc3c5ccccc5n(-c5ccccc5)c43)cc2)cc(-n2c3ccc(C#N)cc3c3c4oc5ccccc5c4ccc32)c1 ; N#Cc1cc(-c2cccc(-n3c4ccccc4c4ccc5oc6ccccc6c5c43)c2)cc(-n2c3ccc(C#N)cc3c3ccc4c5ccccc5oc4c32)c1 ; N#Cc1cc(-c2cccc(-n3c4ccccc4c4c5oc6ccccc6c5ccc43)c2)cc(-n2c3ccc(C#N)cc3c3c4oc5ccccc5c4ccc32)c1]

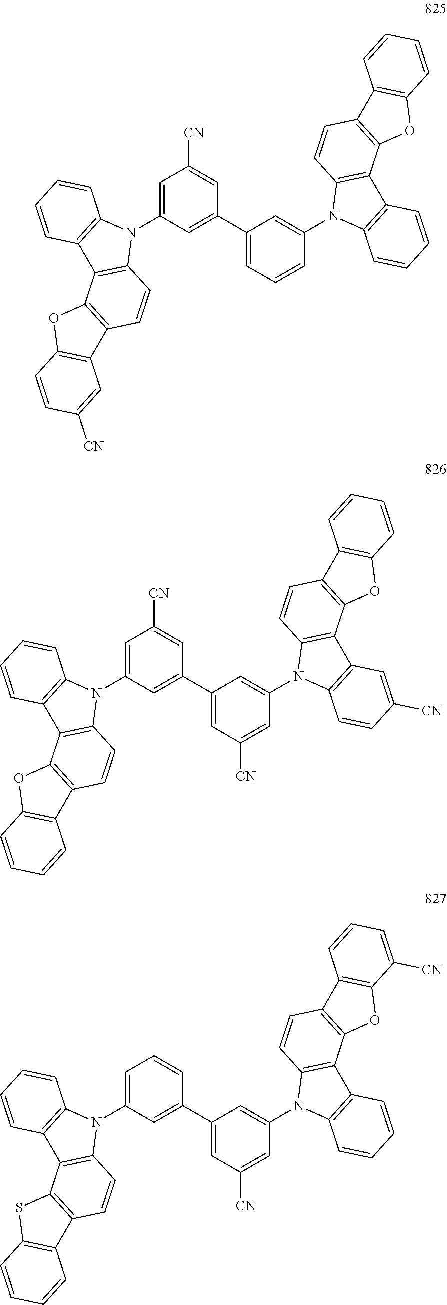 [SMILES: N#Cc1cc(-c2cccc(-n3c4ccccc4c4c5oc6ccccc6c5ccc43)c2)cc(-n2c3ccccc3c3c4oc5ccc(C#N)cc5c4ccc32)c1 ; N#Cc1cc(-c2cc(C#N)cc(-n3c4ccc(C#N)cc4c4c5oc6ccccc6c5ccc43)c2)cc(-n2c3ccccc3c3c4oc5ccccc5c4ccc32)c1 ; N#Cc1cc(-c2cccc(-n3c4ccccc4c4c5sc6ccccc6c5ccc43)c2)cc(-n2c3ccccc3c3c4oc5c(C#N)cccc5c4ccc32)c1]

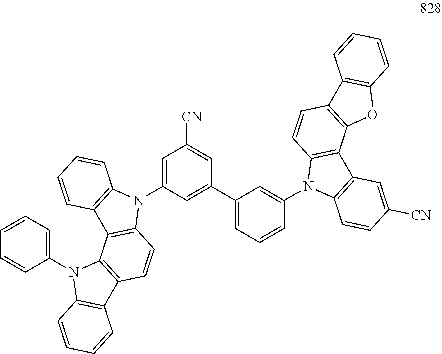 [SMILES: N#Cc1cc(-c2cccc(-n3c4ccc(C#N)cc4c4c5oc6ccccc6c5ccc43)c2)cc(-n2c3ccccc3c3c2ccc2c4ccccc4n(-c4ccccc4)c23)c1]

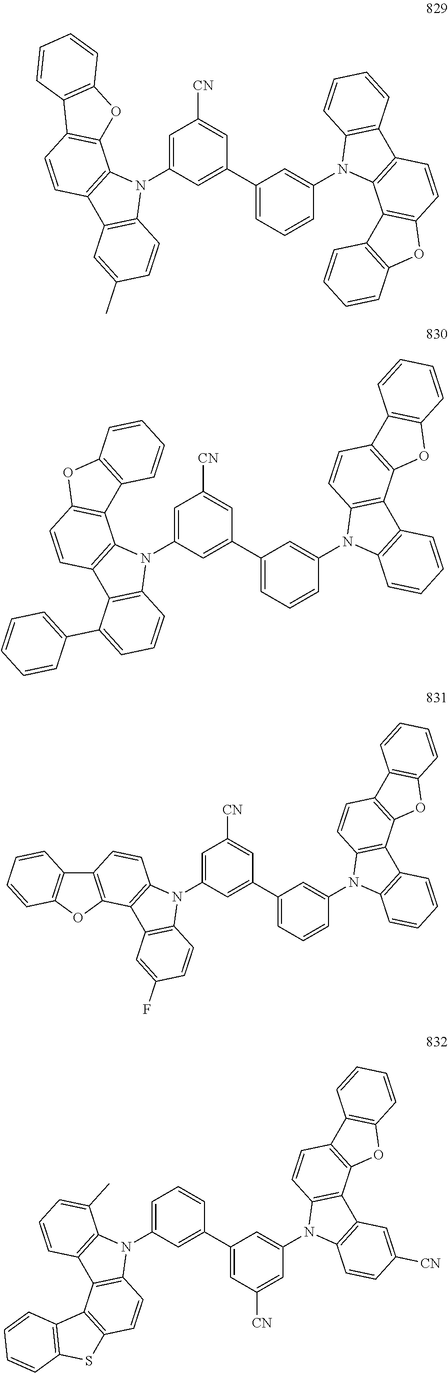 [SMILES: Cc1ccc2c(c1)c1ccc3c4ccccc4oc3c1n2-c1cc(C#N)cc(-c2cccc(-n3c4ccccc4c4ccc5oc6ccccc6c5c43)c2)c1 ; N#Cc1cc(-c2cccc(-n3c4ccccc4c4c5oc6ccccc6c5ccc43)c2)cc(-n2c3cccc(-c4ccccc4)c3c3ccc4oc5ccccc5c4c32)c1 ; N#Cc1cc(-c2cccc(-n3c4ccccc4c4c5oc6ccccc6c5ccc43)c2)cc(-n2c3ccc(F)cc3c3c4oc5ccccc5c4ccc32)c1 ; Cc1cccc2c3c4c(ccc3n(-c3cccc(-c5cc(C#N)cc(-n6c7ccc(C#N)cc7c7c8oc9ccccc9c8ccc76)c5)c3)c12)sc1ccccc14]

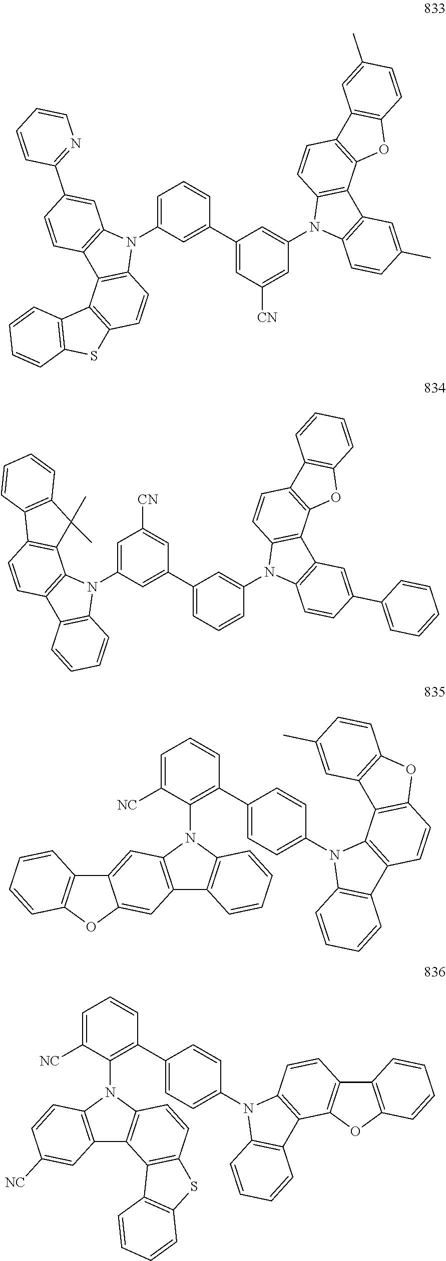 [SMILES: Cc1ccc2oc3c(ccc4c3c3cc(C)ccc3n4-c3cc(C#N)cc(-c4cccc(-n5c6cc(-c7ccccn7)ccc6c6c7c(ccc65)sc5ccccc57)c4)c3)c2c1 ; CC1(C)c2ccccc2-c2ccc3c4ccccc4n(-c4cc(C#N)cc(-c5cccc(-n6c7ccc(-c8ccccc8)cc7c7c8oc9ccccc9c8ccc76)c5)c4)c3c21 ; Cc1ccc2oc3ccc4c5ccccc5n(-c5ccc(-c6cccc(C#N)c6-n6c7ccccc7c7cc8oc9ccccc9c8cc76)cc5)c4c3c2c1 ; N#Cc1ccc2c(c1)c1c3c(ccc1n2-c1c(C#N)cccc1-c1ccc(-n2c4ccccc4c4c5oc6ccccc6c5ccc42)cc1)sc1ccccc13]

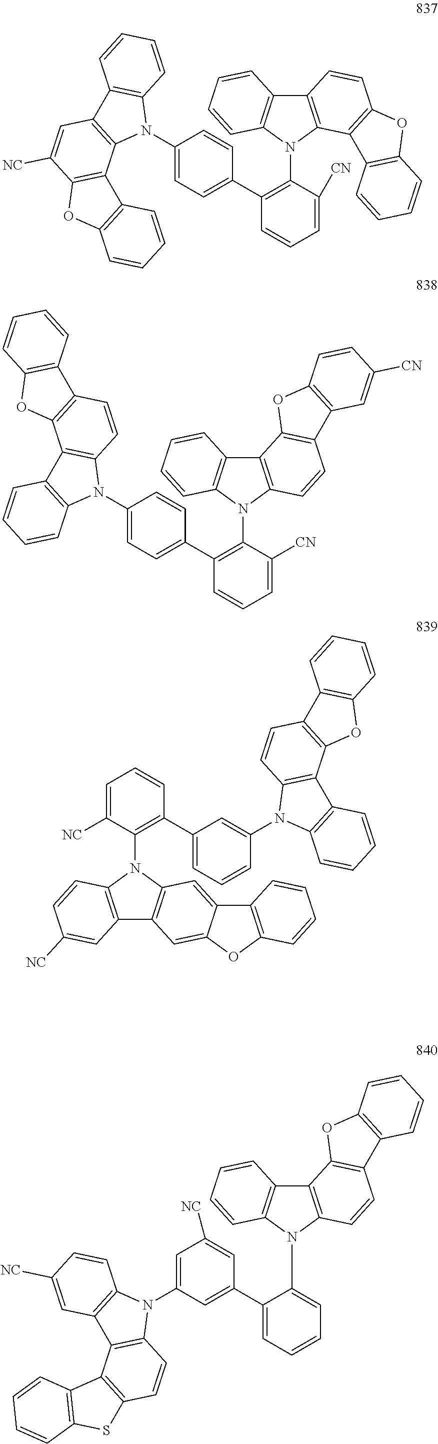

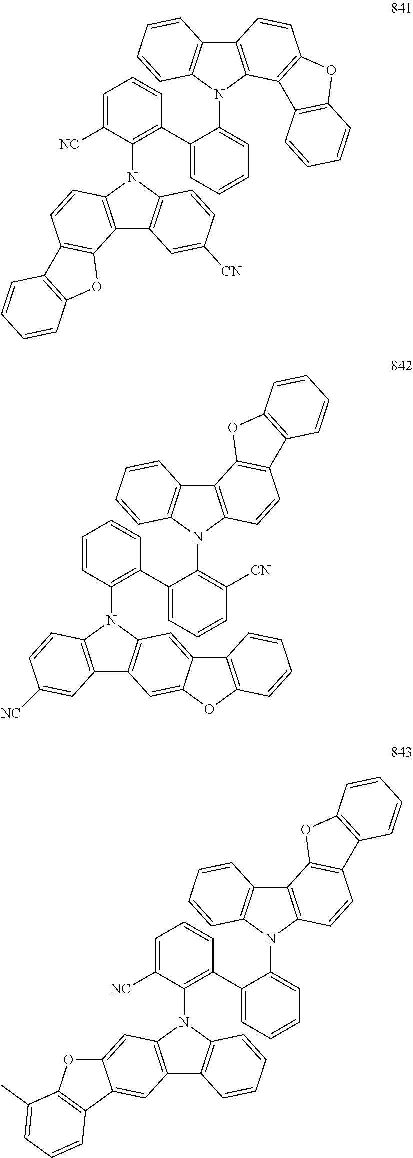 [SMILES: N#Cc1ccc2c(c1)c1c3oc4ccccc4c3ccc1n2-c1c(C#N)cccc1-c1ccccc1-n1c2ccccc2c2ccc3oc4ccccc4c3c21 ; N#Cc1ccc2c(c1)c1cc3oc4ccccc4c3cc1n2-c1ccccc1-c1cccc(C#N)c1-n1c2ccccc2c2c3oc4ccccc4c3ccc21 ; Cc1cccc2c1oc1cc3c(cc12)c1ccccc1n3-c1c(C#N)cccc1-c1ccccc1-n1c2ccccc2c2c3oc4ccccc4c3ccc21]

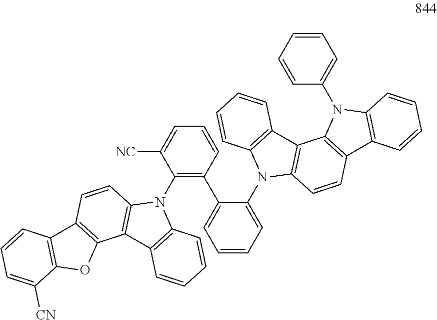 [SMILES: N#Cc1cccc(-c2ccccc2-n2c3ccccc3c3c2ccc2c4ccccc4n(-c4ccccc4)c23)c1-n1c2ccccc2c2c3oc4c(C#N)cccc4c3ccc21]

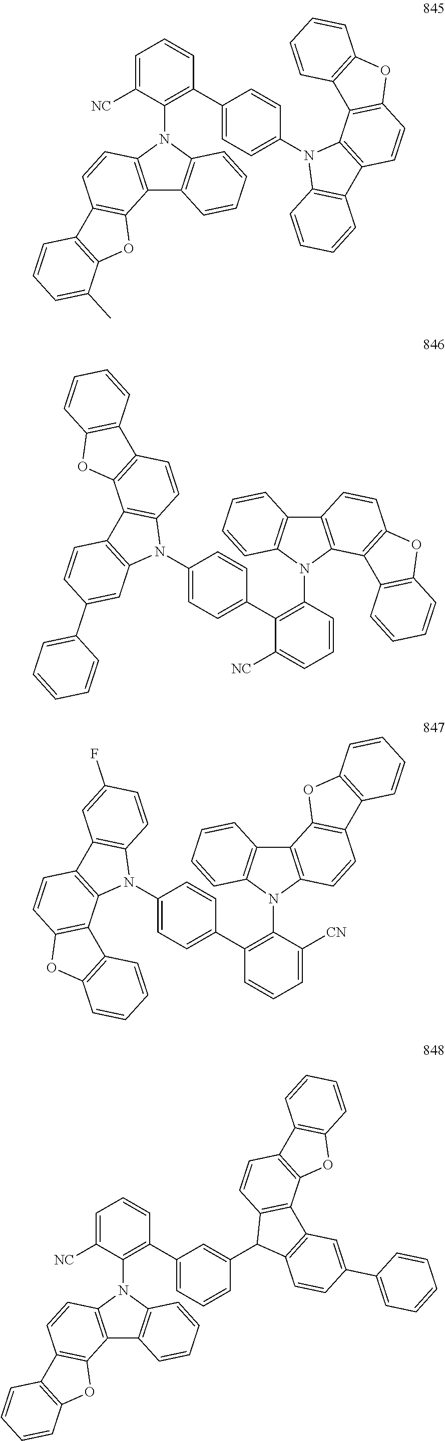

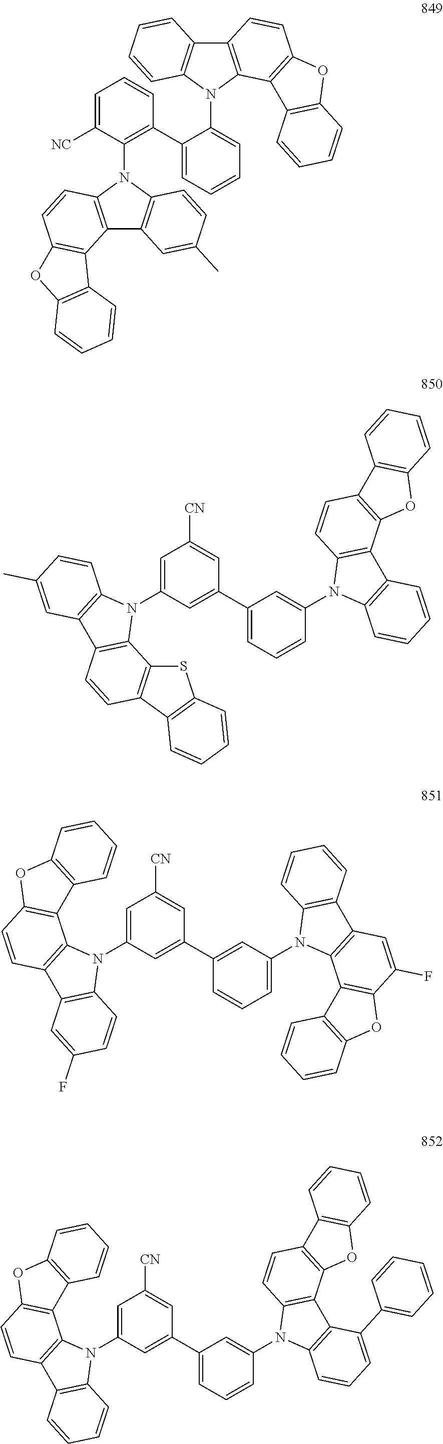 [SMILES: Cc1ccc2c(c1)c1c3c(ccc1n2-c1c(C#N)cccc1-c1ccccc1-n1c2ccccc2c2ccc4oc5ccccc5c4c21)oc1ccccc13 ; Cc1ccc2c(c1)c1ccc3c4ccccc4sc3c1n2-c1cc(C#N)cc(-c2cccc(-n3c4ccccc4c4c5oc6ccccc6c5ccc43)c2)c1 ; N#Cc1cc(-c2cccc(-n3c4ccccc4c4cc(F)c5oc6ccccc6c5c43)c2)cc(-n2c3ccc(F)cc3c3ccc4oc5ccccc5c4c32)c1 ; N#Cc1cc(-c2cccc(-n3c4cccc(-c5ccccc5)c4c4c5oc6ccccc6c5ccc43)c2)cc(-n2c3ccccc3c3ccc4oc5ccccc5c4c32)c1]

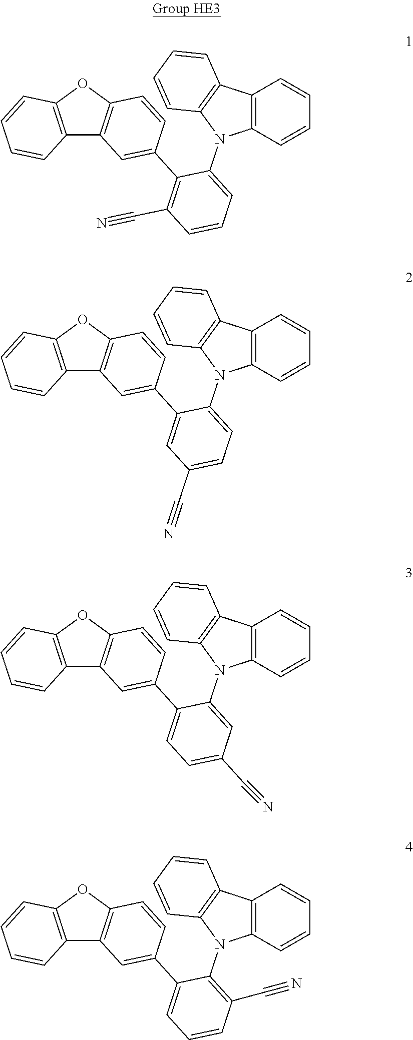 [SMILES: N#Cc1cccc(-n2c3ccccc3c3ccccc32)c1-c1ccc2oc3ccccc3c2c1 ; N#Cc1ccc(-n2c3ccccc3c3ccccc32)c(-c2ccc3oc4ccccc4c3c2)c1 ; N#Cc1ccc(-c2ccc3oc4ccccc4c3c2)c(-n2c3ccccc3c3ccccc32)c1 ; N#Cc1cccc(-c2ccc3oc4ccccc4c3c2)c1-n1c2ccccc2c2ccccc21]

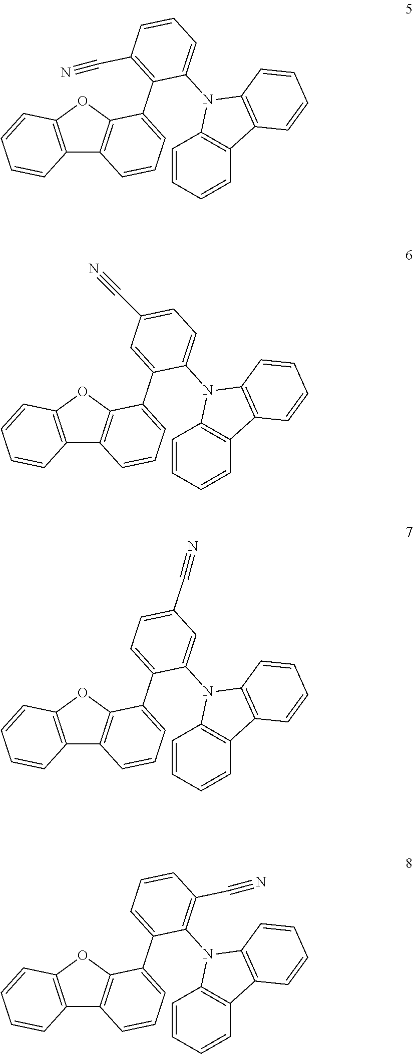

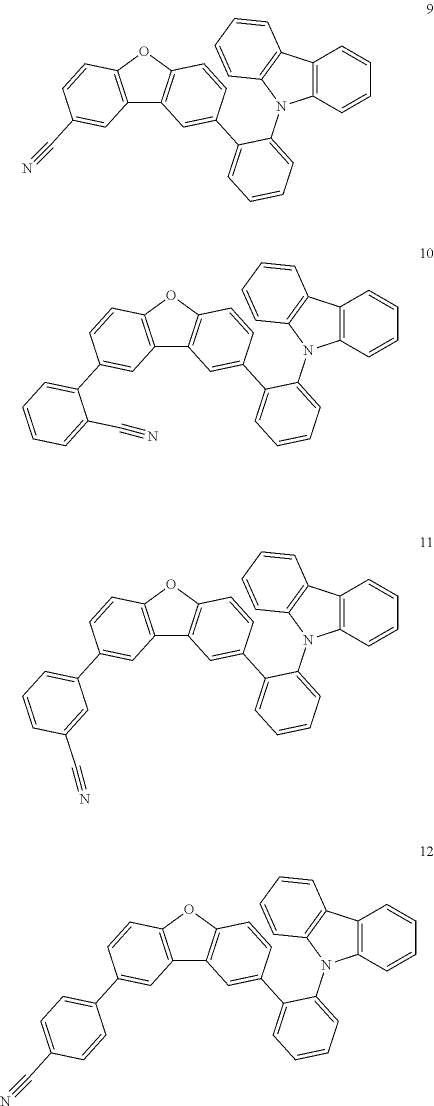 [SMILES: N#Cc1ccc2oc3ccc(-c4ccccc4-n4c5ccccc5c5ccccc54)cc3c2c1 ; N#Cc1ccccc1-c1ccc2oc3ccc(-c4ccccc4-n4c5ccccc5c5ccccc54)cc3c2c1 ; N#Cc1cccc(-c2ccc3oc4ccc(-c5ccccc5-n5c6ccccc6c6ccccc65)cc4c3c2)c1 ; N#Cc1ccc(-c2ccc3oc4ccc(-c5ccccc5-n5c6ccccc6c6ccccc65)cc4c3c2)cc1]

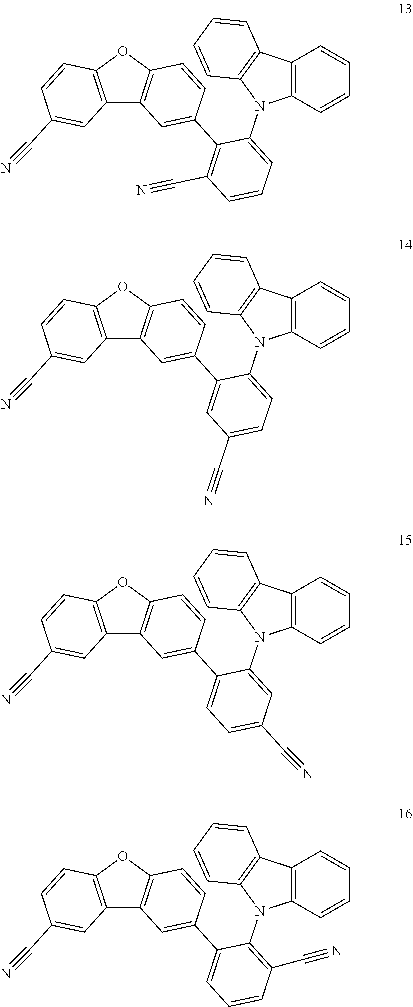 [SMILES: N#Cc1ccc2oc3ccc(-c4c(C#N)cccc4-n4c5ccccc5c5ccccc54)cc3c2c1 ; N#Cc1ccc(-n2c3ccccc3c3ccccc32)c(-c2ccc3oc4ccc(C#N)cc4c3c2)c1 ; N#Cc1ccc(-c2ccc3oc4ccc(C#N)cc4c3c2)c(-n2c3ccccc3c3ccccc32)c1 ; N#Cc1ccc2oc3ccc(-c4cccc(C#N)c4-n4c5ccccc5c5ccccc54)cc3c2c1]

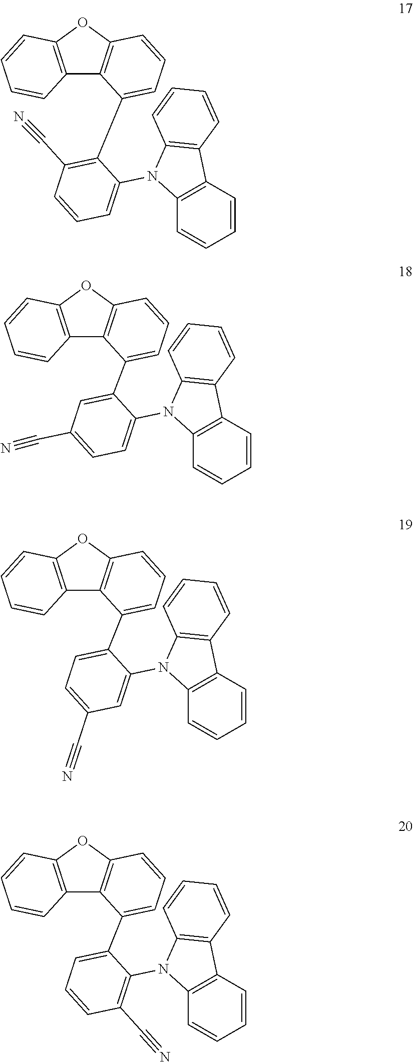 [SMILES: N#Cc1cccc(-n2c3ccccc3c3ccccc32)c1-c1cccc2oc3ccccc3c12 ; N#Cc1ccc(-n2c3ccccc3c3ccccc32)c(-c2cccc3oc4ccccc4c23)c1 ; N#Cc1ccc(-c2cccc3oc4ccccc4c23)c(-n2c3ccccc3c3ccccc32)c1 ; N#Cc1cccc(-c2cccc3oc4ccccc4c23)c1-n1c2ccccc2c2ccccc21]

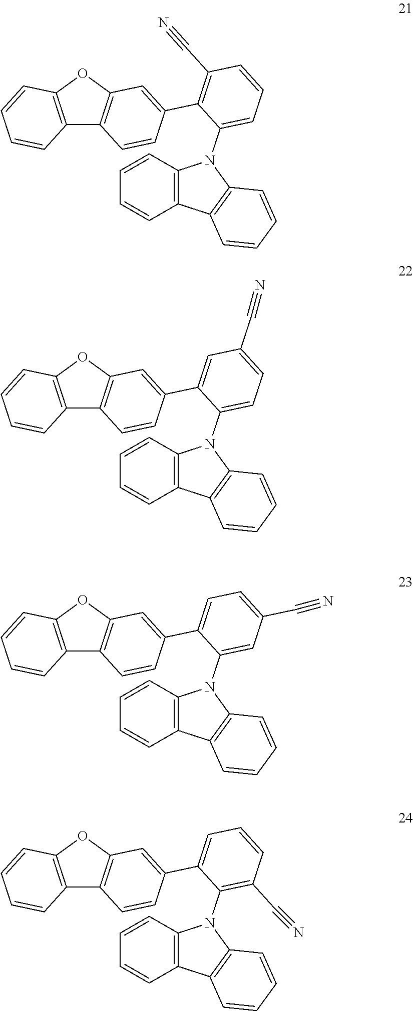

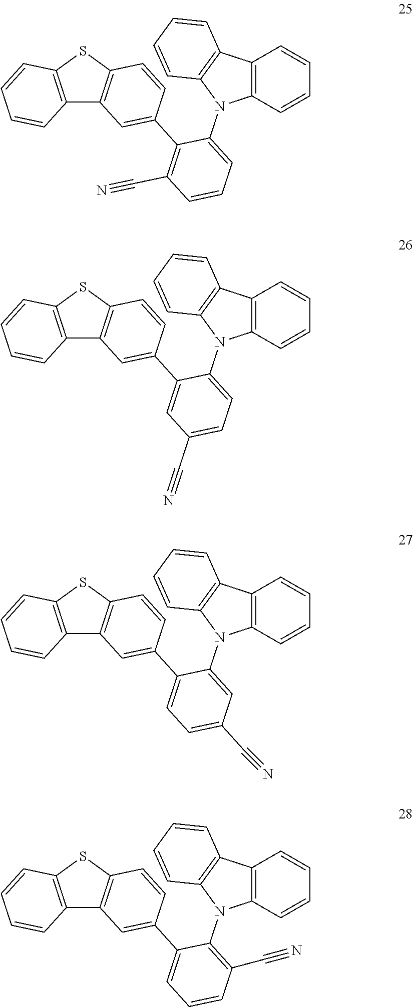 [SMILES: N#Cc1cccc(-n2c3ccccc3c3ccccc32)c1-c1ccc2sc3ccccc3c2c1 ; N#Cc1ccc(-n2c3ccccc3c3ccccc32)c(-c2ccc3sc4ccccc4c3c2)c1 ; N#Cc1ccc(-c2ccc3sc4ccccc4c3c2)c(-n2c3ccccc3c3ccccc32)c1 ; N#Cc1cccc(-c2ccc3sc4ccccc4c3c2)c1-n1c2ccccc2c2ccccc21]

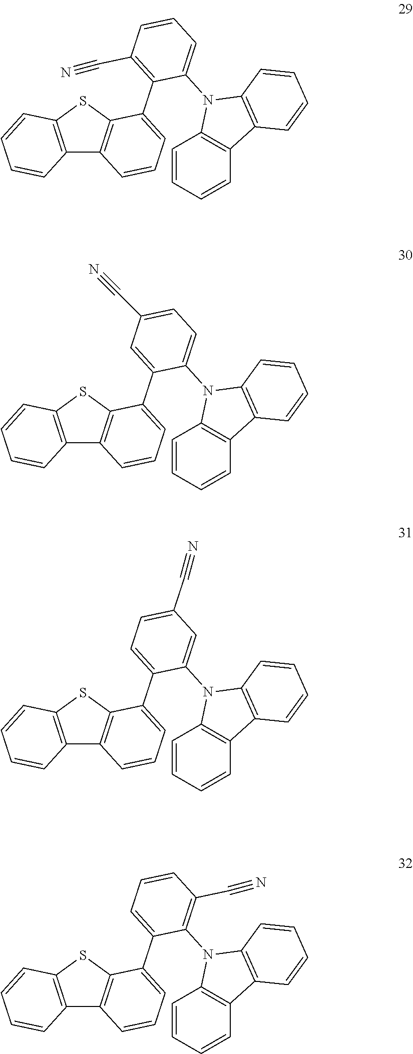

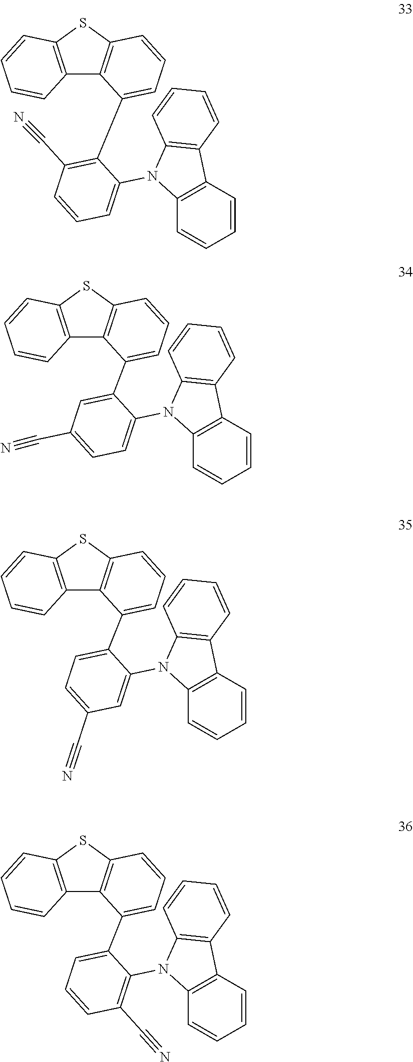 [SMILES: N#Cc1cccc(-n2c3ccccc3c3ccccc32)c1-c1cccc2sc3ccccc3c12 ; N#Cc1ccc(-n2c3ccccc3c3ccccc32)c(-c2cccc3sc4ccccc4c23)c1 ; N#Cc1ccc(-c2cccc3sc4ccccc4c23)c(-n2c3ccccc3c3ccccc32)c1 ; N#Cc1cccc(-c2cccc3sc4ccccc4c23)c1-n1c2ccccc2c2ccccc21]

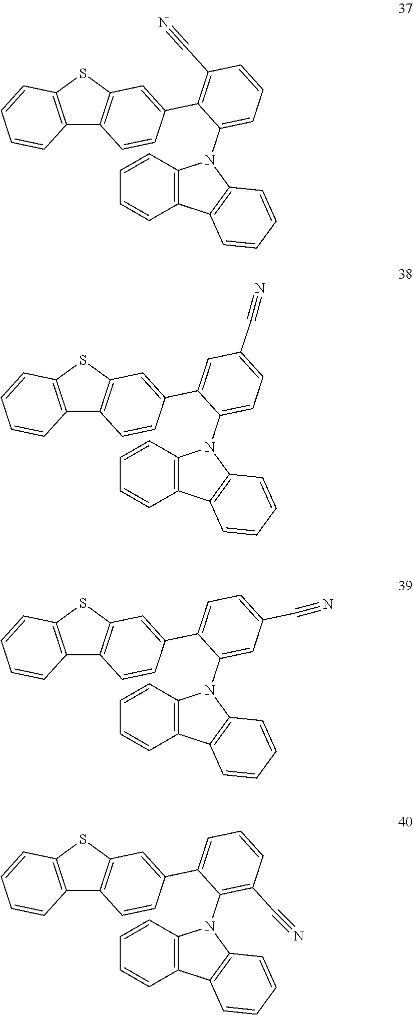

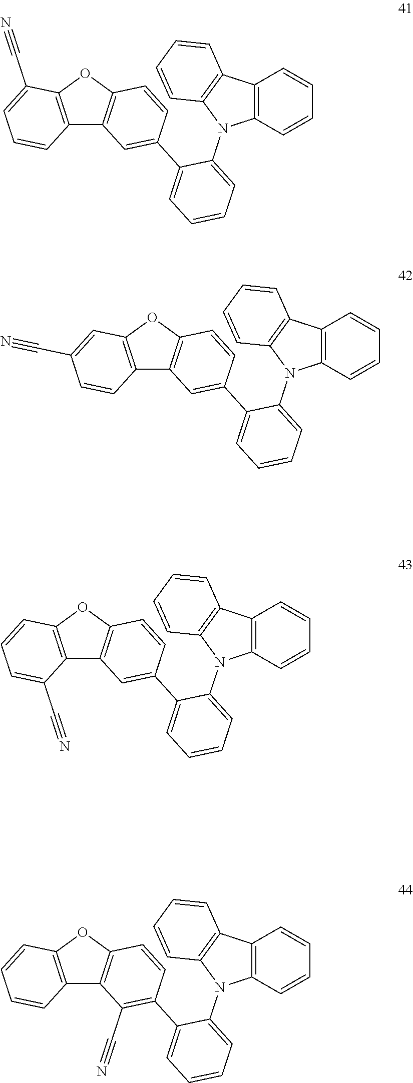 [SMILES: N#Cc1cccc2c1oc1ccc(-c3ccccc3-n3c4ccccc4c4ccccc43)cc12 ; N#Cc1ccc2c(c1)oc1ccc(-c3ccccc3-n3c4ccccc4c4ccccc43)cc12 ; N#Cc1cccc2oc3ccc(-c4ccccc4-n4c5ccccc5c5ccccc54)cc3c12 ; N#Cc1c(-c2ccccc2-n2c3ccccc3c3ccccc32)ccc2oc3ccccc3c12]

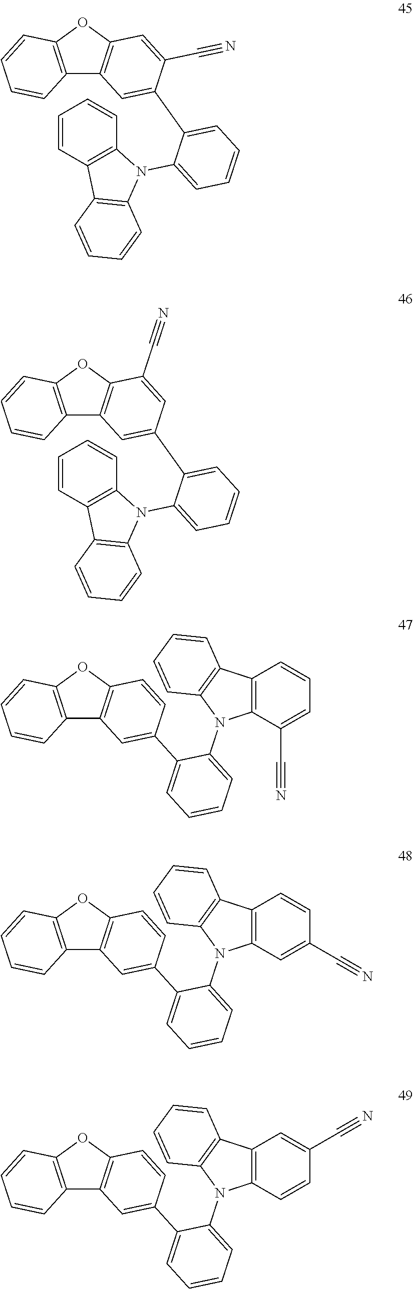 [SMILES: N#Cc1cc2oc3ccccc3c2cc1-c1ccccc1-n1c2ccccc2c2ccccc21 ; N#Cc1cc(-c2ccccc2-n2c3ccccc3c3ccccc32)cc2c1oc1ccccc12 ; N#Cc1cccc2c3ccccc3n(-c3ccccc3-c3ccc4oc5ccccc5c4c3)c12 ; N#Cc1ccc2c3ccccc3n(-c3ccccc3-c3ccc4oc5ccccc5c4c3)c2c1 ; N#Cc1ccc2c(c1)c1ccccc1n2-c1ccccc1-c1ccc2oc3ccccc3c2c1]

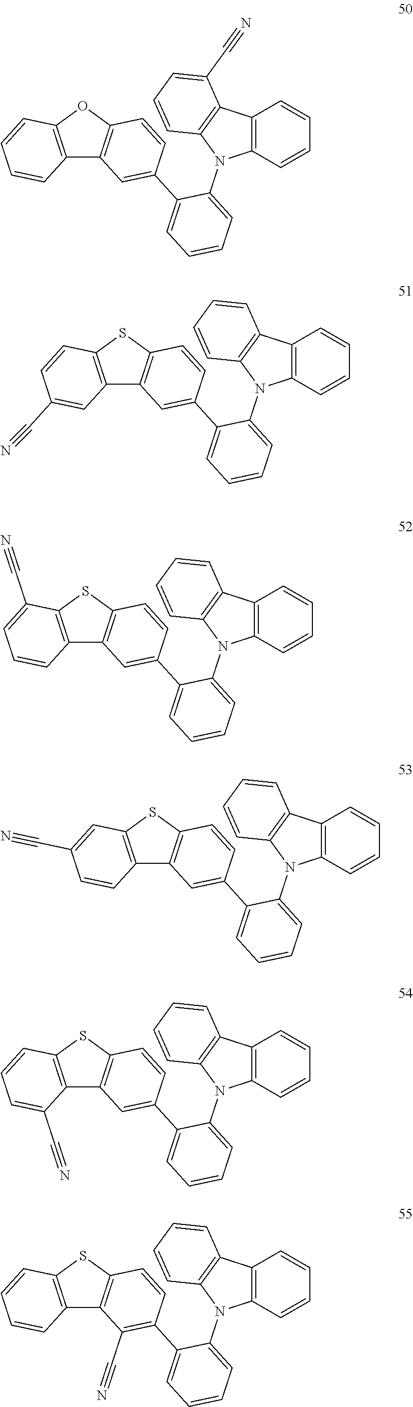

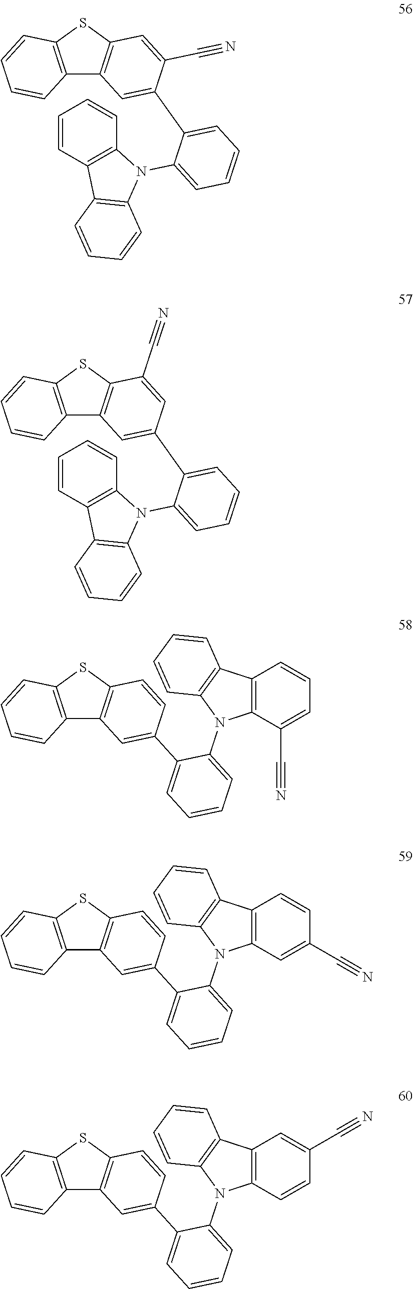 [SMILES: N#Cc1cc2sc3ccccc3c2cc1-c1ccccc1-n1c2ccccc2c2ccccc21 ; N#Cc1cc(-c2ccccc2-n2c3ccccc3c3ccccc32)cc2c1sc1ccccc12 ; N#Cc1cccc2c3ccccc3n(-c3ccccc3-c3ccc4sc5ccccc5c4c3)c12 ; N#Cc1ccc2c3ccccc3n(-c3ccccc3-c3ccc4sc5ccccc5c4c3)c2c1 ; N#Cc1ccc2c(c1)c1ccccc1n2-c1ccccc1-c1ccc2sc3ccccc3c2c1]

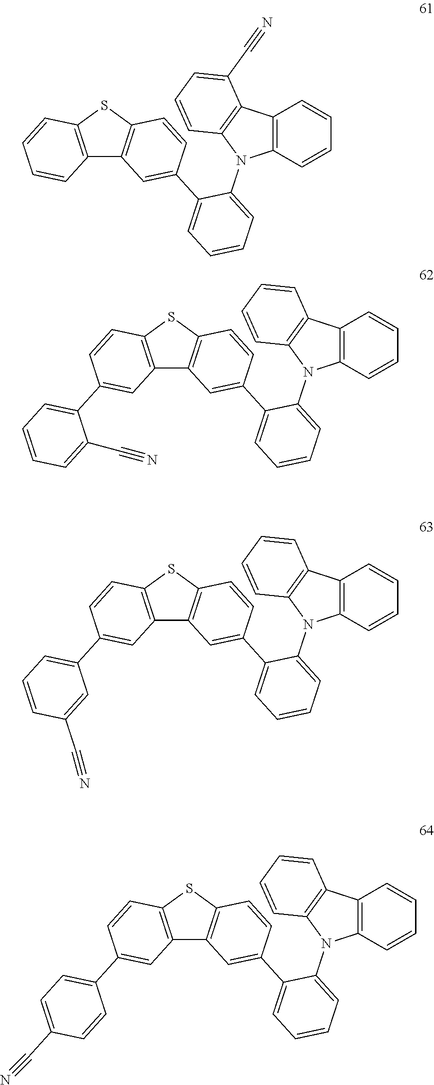

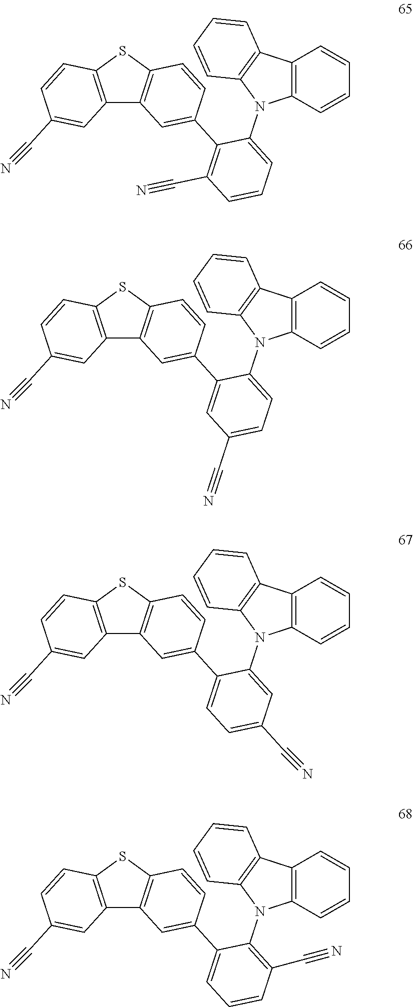 [SMILES: N#Cc1ccc2sc3ccc(-c4c(C#N)cccc4-n4c5ccccc5c5ccccc54)cc3c2c1 ; N#Cc1ccc(-n2c3ccccc3c3ccccc32)c(-c2ccc3sc4ccc(C#N)cc4c3c2)c1 ; N#Cc1ccc(-c2ccc3sc4ccc(C#N)cc4c3c2)c(-n2c3ccccc3c3ccccc32)c1 ; N#Cc1ccc2sc3ccc(-c4cccc(C#N)c4-n4c5ccccc5c5ccccc54)cc3c2c1]

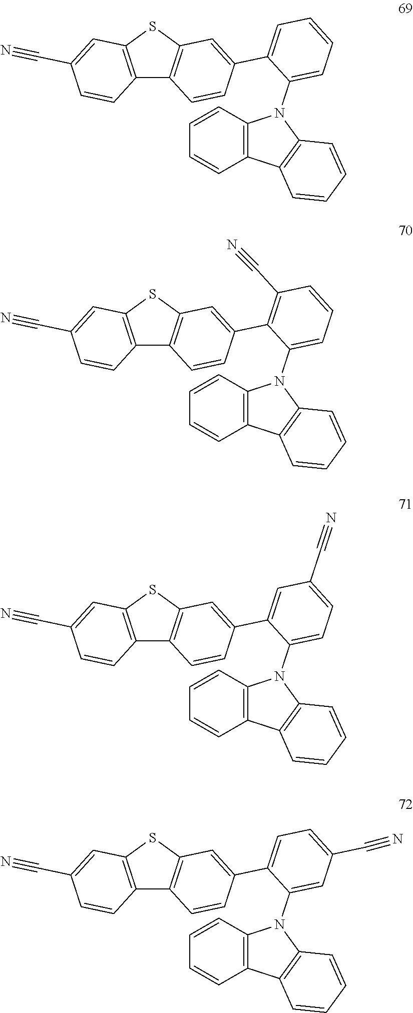 [SMILES: N#Cc1ccc2c(c1)sc1cc(-c3ccccc3-n3c4ccccc4c4ccccc43)ccc12 ; N#Cc1ccc2c(c1)sc1cc(-c3c(C#N)cccc3-n3c4ccccc4c4ccccc43)ccc12 ; N#Cc1ccc(-n2c3ccccc3c3ccccc32)c(-c2ccc3c(c2)sc2cc(C#N)ccc23)c1 ; N#Cc1ccc(-c2ccc3c(c2)sc2cc(C#N)ccc23)c(-n2c3ccccc3c3ccccc32)c1]

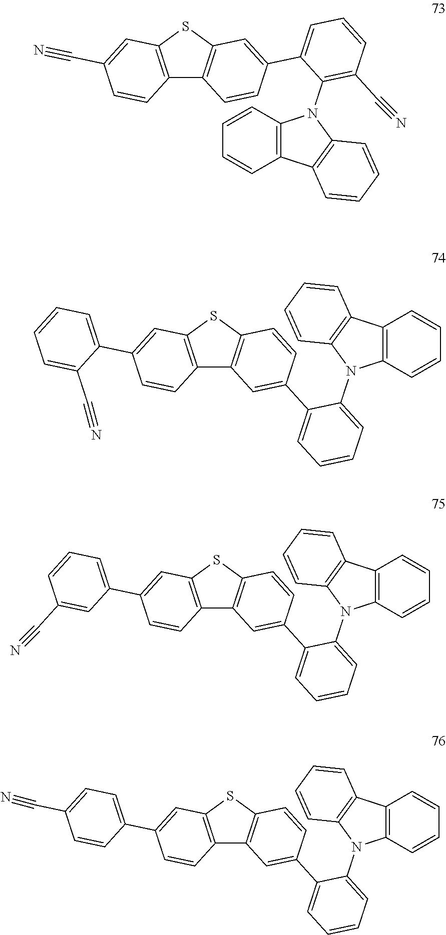 [SMILES: N#Cc1ccc2c(c1)sc1cc(-c3cccc(C#N)c3-n3c4ccccc4c4ccccc43)ccc12 ; N#Cc1ccccc1-c1ccc2c(c1)sc1ccc(-c3ccccc3-n3c4ccccc4c4ccccc43)cc12 ; N#Cc1cccc(-c2ccc3c(c2)sc2ccc(-c4ccccc4-n4c5ccccc5c5ccccc54)cc23)c1 ; N#Cc1ccc(-c2ccc3c(c2)sc2ccc(-c4ccccc4-n4c5ccccc5c5ccccc54)cc23)cc1]

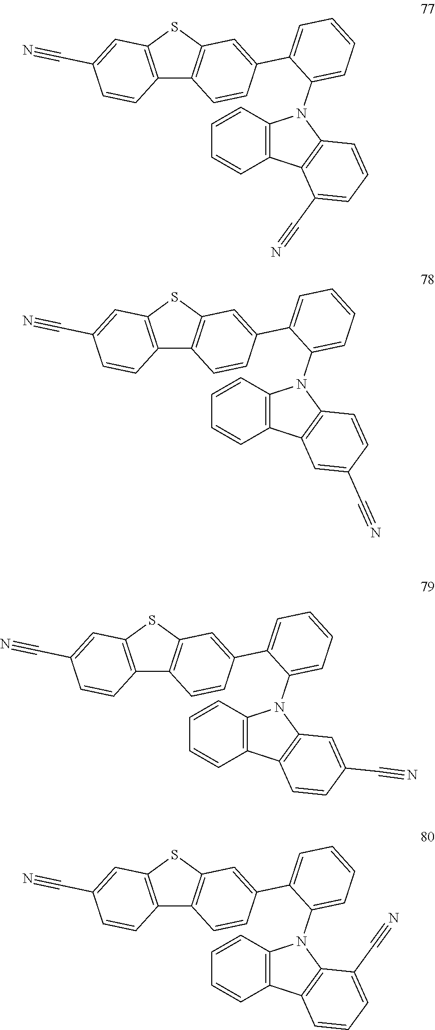 [SMILES: N#Cc1ccc2c(c1)sc1cc(-c3ccccc3-n3c4ccccc4c4c(C#N)cccc43)ccc12 ; N#Cc1ccc2c(c1)sc1cc(-c3ccccc3-n3c4ccccc4c4cc(C#N)ccc43)ccc12 ; N#Cc1ccc2c(c1)sc1cc(-c3ccccc3-n3c4ccccc4c4ccc(C#N)cc43)ccc12 ; N#Cc1ccc2c(c1)sc1cc(-c3ccccc3-n3c4ccccc4c4cccc(C#N)c43)ccc12]

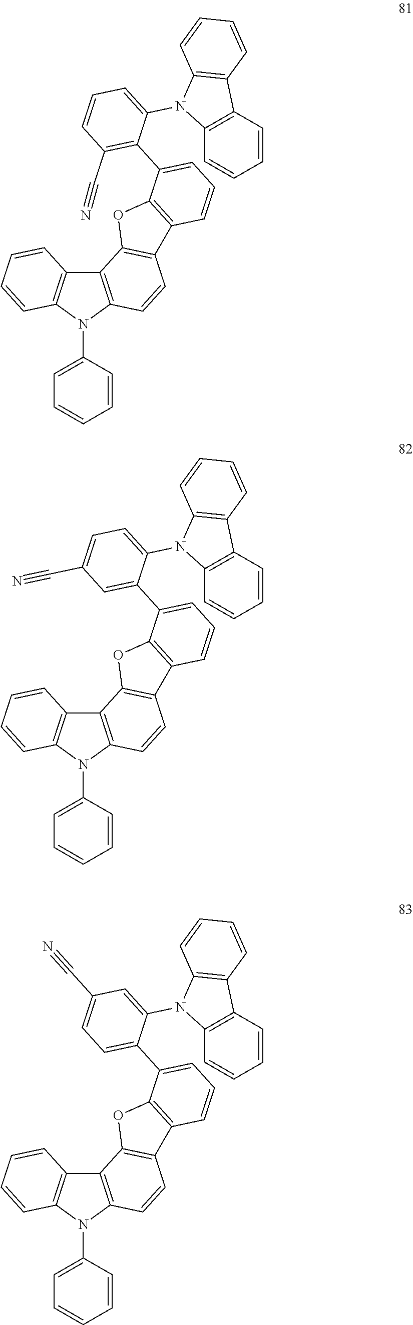 [SMILES: N#Cc1cccc(-n2c3ccccc3c3ccccc32)c1-c1cccc2c1oc1c2ccc2c1c1ccccc1n2-c1ccccc1 ; N#Cc1ccc(-n2c3ccccc3c3ccccc32)c(-c2cccc3c2oc2c3ccc3c2c2ccccc2n3-c2ccccc2)c1 ; N#Cc1ccc(-c2cccc3c2oc2c3ccc3c2c2ccccc2n3-c2ccccc2)c(-n2c3ccccc3c3ccccc32)c1]

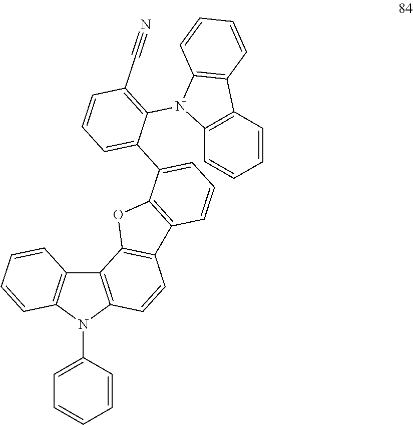 [SMILES: N#Cc1cccc(-c2cccc3c2oc2c3ccc3c2c2ccccc2n3-c2ccccc2)c1-n1c2ccccc2c2ccccc21]

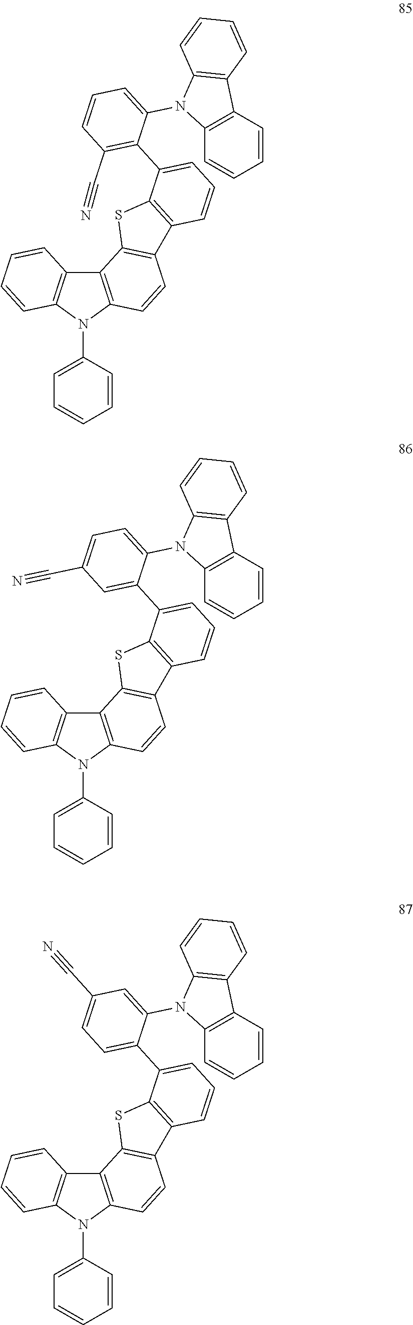 [SMILES: N#Cc1cccc(-n2c3ccccc3c3ccccc32)c1-c1cccc2c1sc1c2ccc2c1c1ccccc1n2-c1ccccc1 ; N#Cc1ccc(-n2c3ccccc3c3ccccc32)c(-c2cccc3c2sc2c3ccc3c2c2ccccc2n3-c2ccccc2)c1 ; N#Cc1ccc(-c2cccc3c2sc2c3ccc3c2c2ccccc2n3-c2ccccc2)c(-n2c3ccccc3c3ccccc32)c1]

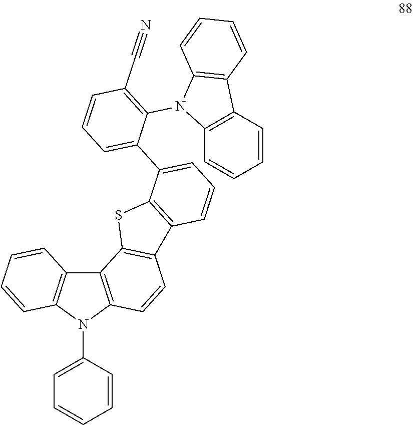 [SMILES: N#Cc1cccc(-c2cccc3c2sc2c3ccc3c2c2ccccc2n3-c2ccccc2)c1-n1c2ccccc2c2ccccc21]

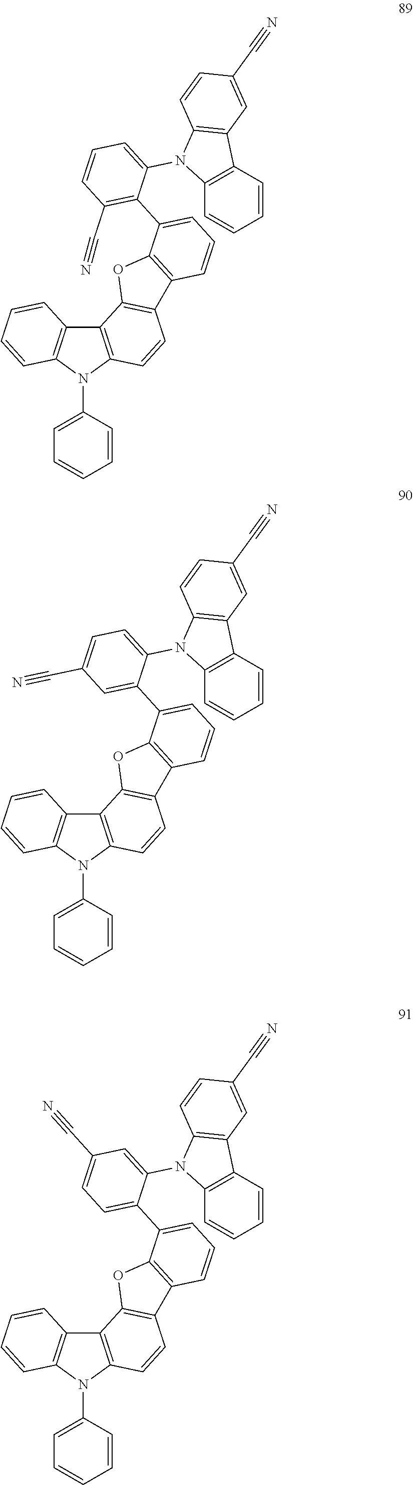 [SMILES: N#Cc1ccc2c(c1)c1ccccc1n2-c1cccc(C#N)c1-c1cccc2c1oc1c2ccc2c1c1ccccc1n2-c1ccccc1 ; N#Cc1ccc(-n2c3ccccc3c3cc(C#N)ccc32)c(-c2cccc3c2oc2c3ccc3c2c2ccccc2n3-c2ccccc2)c1 ; N#Cc1ccc(-c2cccc3c2oc2c3ccc3c2c2ccccc2n3-c2ccccc2)c(-n2c3ccccc3c3cc(C#N)ccc32)c1]

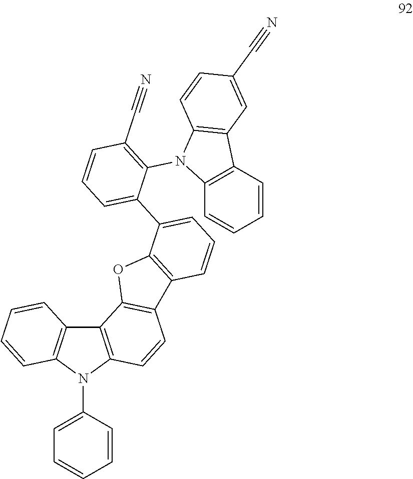 [SMILES: N#Cc1ccc2c(c1)c1ccccc1n2-c1c(C#N)cccc1-c1cccc2c1oc1c2ccc2c1c1ccccc1n2-c1ccccc1]

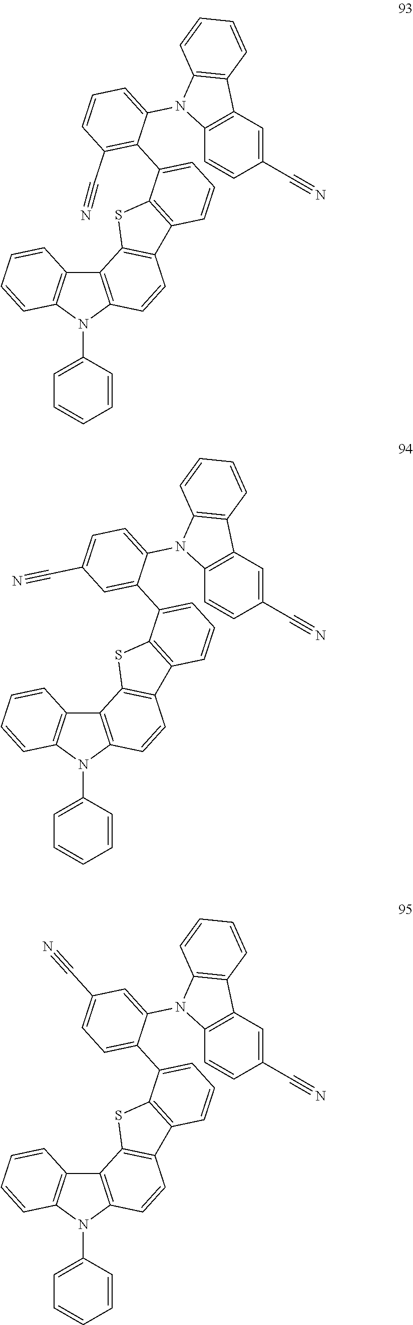 [SMILES: N#Cc1ccc2c(c1)c1ccccc1n2-c1cccc(C#N)c1-c1cccc2c1sc1c2ccc2c1c1ccccc1n2-c1ccccc1 ; N#Cc1ccc(-n2c3ccccc3c3cc(C#N)ccc32)c(-c2cccc3c2sc2c3ccc3c2c2ccccc2n3-c2ccccc2)c1 ; N#Cc1ccc(-c2cccc3c2sc2c3ccc3c2c2ccccc2n3-c2ccccc2)c(-n2c3ccccc3c3cc(C#N)ccc32)c1]

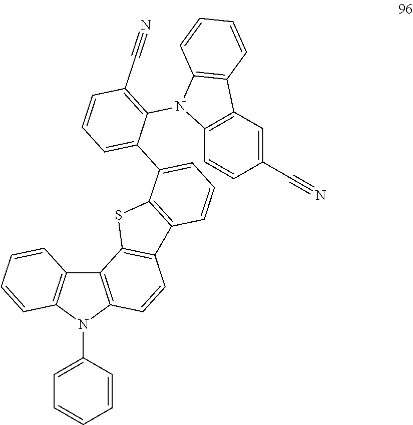 [SMILES: N#Cc1ccc2c(c1)c1ccccc1n2-c1c(C#N)cccc1-c1cccc2c1sc1c2ccc2c1c1ccccc1n2-c1ccccc1]

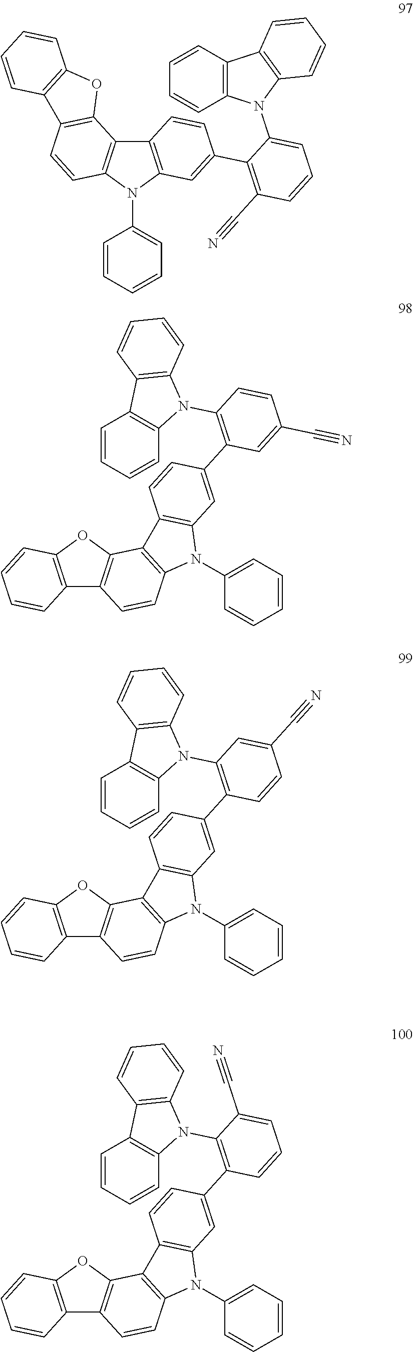

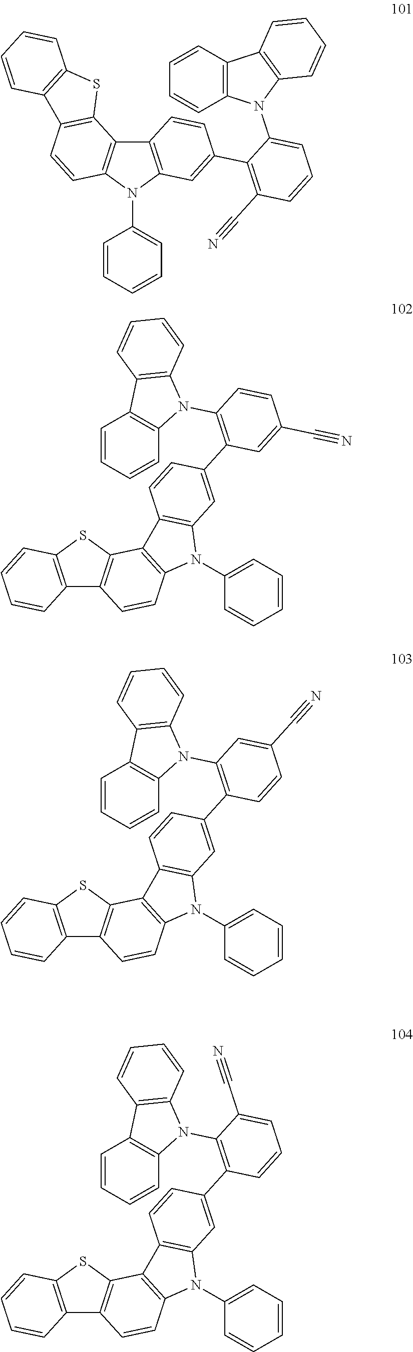

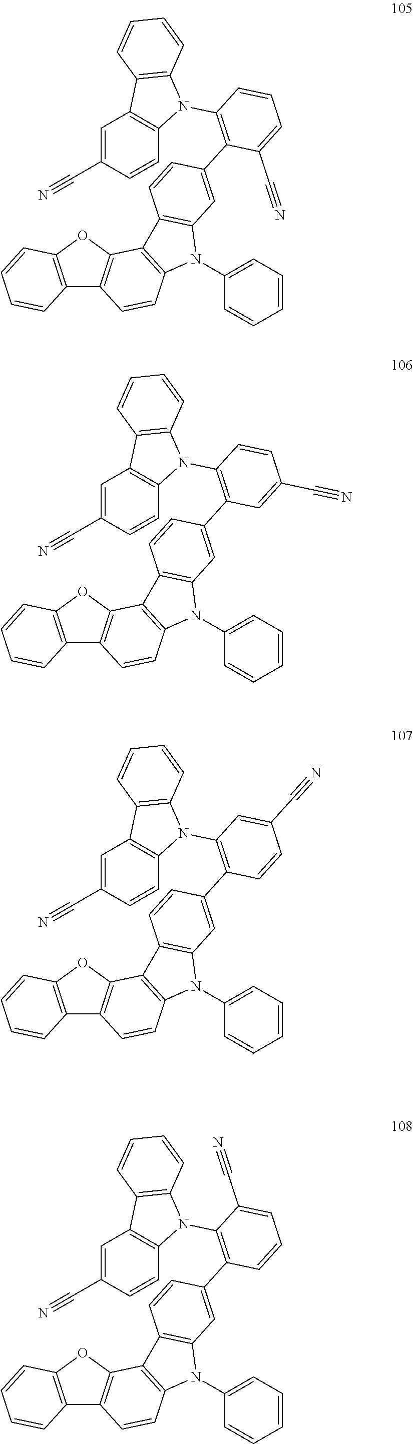 [SMILES: N#Cc1ccc2c(c1)c1ccccc1n2-c1cccc(C#N)c1-c1ccc2c3c4oc5ccccc5c4ccc3n(-c3ccccc3)c2c1 ; N#Cc1ccc(-n2c3ccccc3c3cc(C#N)ccc32)c(-c2ccc3c4c5oc6ccccc6c5ccc4n(-c4ccccc4)c3c2)c1 ; N#Cc1ccc(-c2ccc3c4c5oc6ccccc6c5ccc4n(-c4ccccc4)c3c2)c(-n2c3ccccc3c3cc(C#N)ccc32)c1 ; N#Cc1ccc2c(c1)c1ccccc1n2-c1c(C#N)cccc1-c1ccc2c3c4oc5ccccc5c4ccc3n(-c3ccccc3)c2c1]

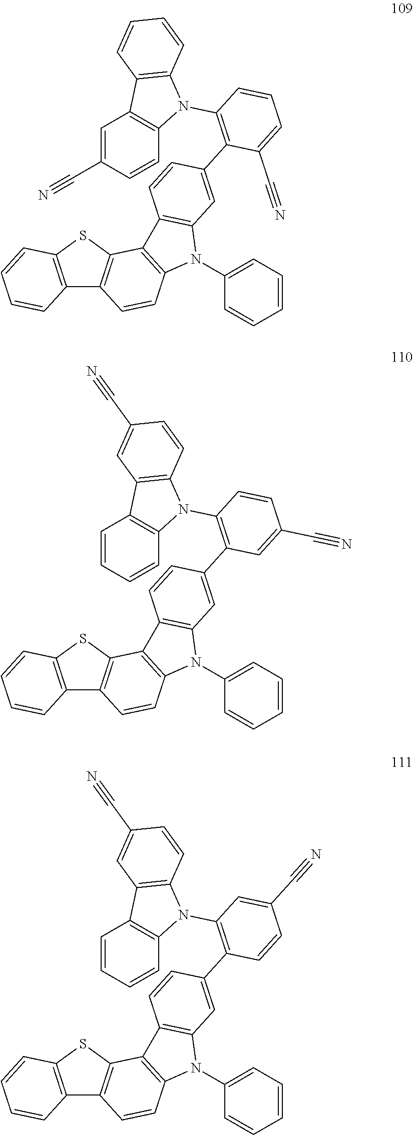 [SMILES: N#Cc1ccc2c(c1)c1ccccc1n2-c1cccc(C#N)c1-c1ccc2c3c4sc5ccccc5c4ccc3n(-c3ccccc3)c2c1 ; N#Cc1ccc(-n2c3ccccc3c3cc(C#N)ccc32)c(-c2ccc3c4c5sc6ccccc6c5ccc4n(-c4ccccc4)c3c2)c1 ; N#Cc1ccc(-c2ccc3c4c5sc6ccccc6c5ccc4n(-c4ccccc4)c3c2)c(-n2c3ccccc3c3cc(C#N)ccc32)c1]

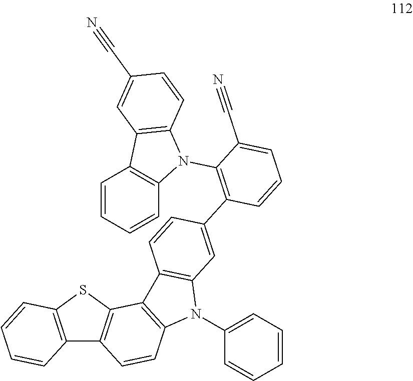 [SMILES: N#Cc1ccc2c(c1)c1ccccc1n2-c1c(C#N)cccc1-c1ccc2c3c4sc5ccccc5c4ccc3n(-c3ccccc3)c2c1]

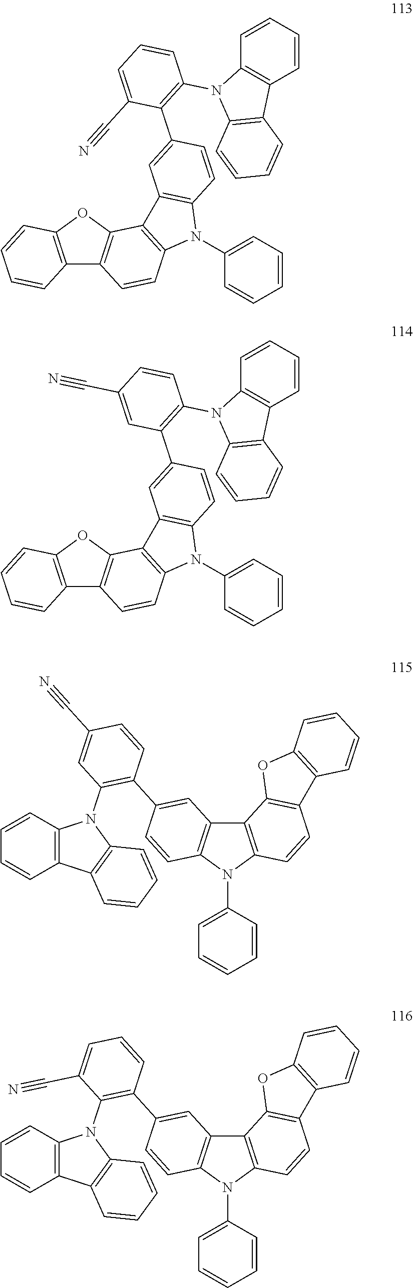

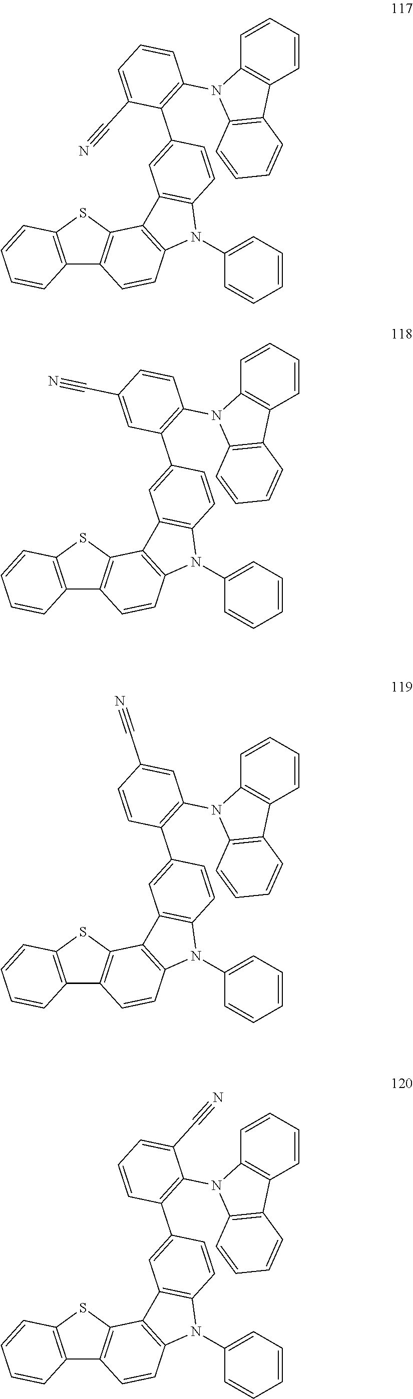

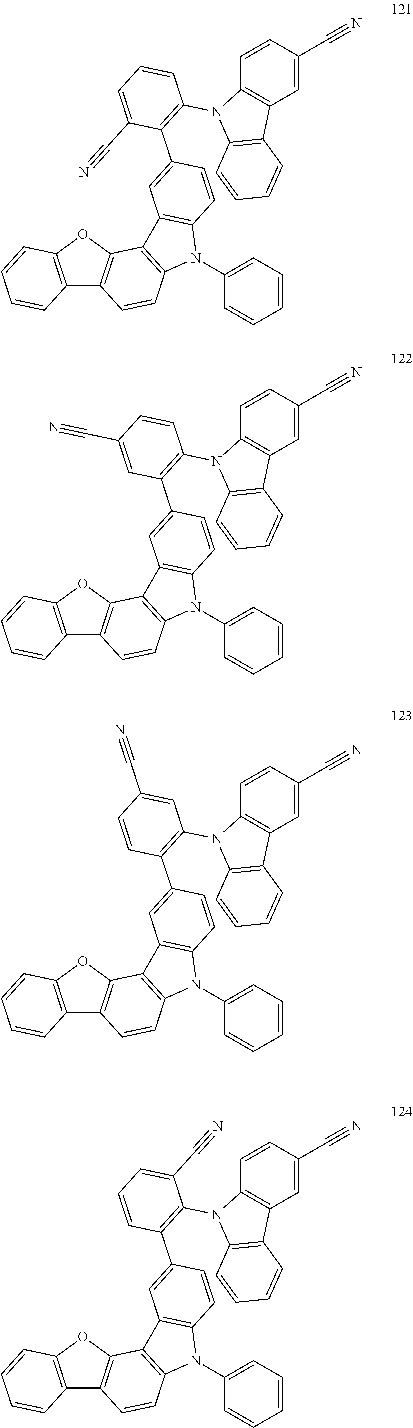 [SMILES: N#Cc1ccc2c(c1)c1ccccc1n2-c1cccc(C#N)c1-c1ccc2c(c1)c1c3oc4ccccc4c3ccc1n2-c1ccccc1 ; N#Cc1ccc(-n2c3ccccc3c3cc(C#N)ccc32)c(-c2ccc3c(c2)c2c4oc5ccccc5c4ccc2n3-c2ccccc2)c1 ; N#Cc1ccc(-c2ccc3c(c2)c2c4oc5ccccc5c4ccc2n3-c2ccccc2)c(-n2c3ccccc3c3cc(C#N)ccc32)c1 ; N#Cc1ccc2c(c1)c1ccccc1n2-c1c(C#N)cccc1-c1ccc2c(c1)c1c3oc4ccccc4c3ccc1n2-c1ccccc1]

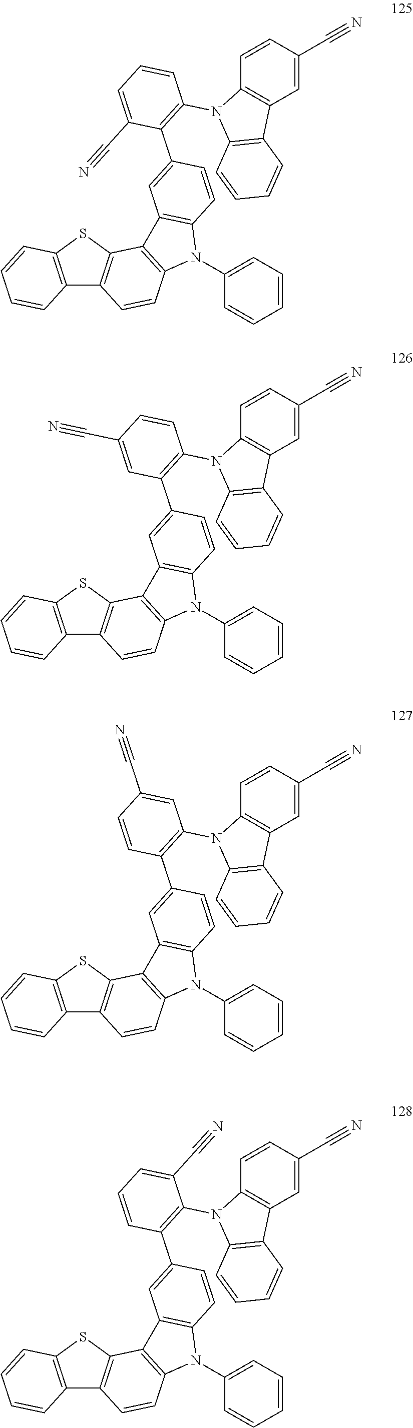 [SMILES: N#Cc1ccc2c(c1)c1ccccc1n2-c1cccc(C#N)c1-c1ccc2c(c1)c1c3sc4ccccc4c3ccc1n2-c1ccccc1 ; N#Cc1ccc(-n2c3ccccc3c3cc(C#N)ccc32)c(-c2ccc3c(c2)c2c4sc5ccccc5c4ccc2n3-c2ccccc2)c1 ; N#Cc1ccc(-c2ccc3c(c2)c2c4sc5ccccc5c4ccc2n3-c2ccccc2)c(-n2c3ccccc3c3cc(C#N)ccc32)c1 ; N#Cc1ccc2c(c1)c1ccccc1n2-c1c(C#N)cccc1-c1ccc2c(c1)c1c3sc4ccccc4c3ccc1n2-c1ccccc1]

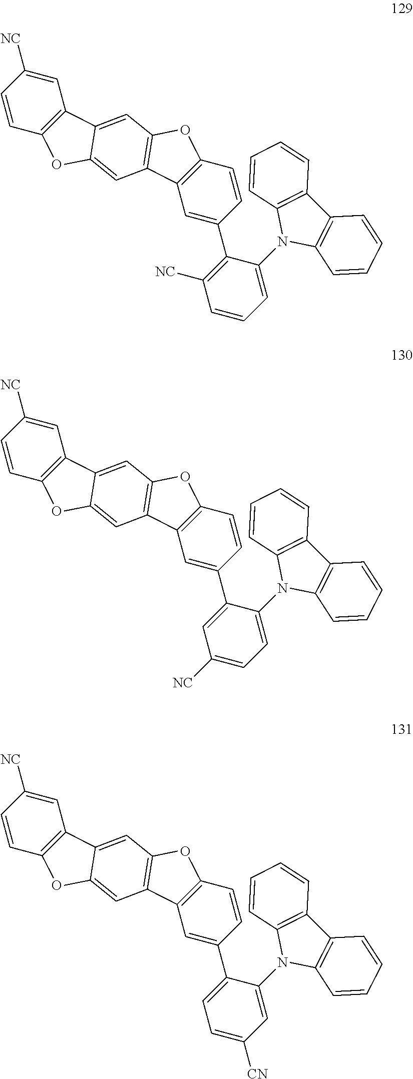 [SMILES: N#Cc1ccc2oc3cc4c(cc3c2c1)oc1ccc(-c2c(C#N)cccc2-n2c3ccccc3c3ccccc32)cc14 ; N#Cc1ccc(-n2c3ccccc3c3ccccc32)c(-c2ccc3oc4cc5c(cc4c3c2)oc2ccc(C#N)cc25)c1 ; N#Cc1ccc(-c2ccc3oc4cc5c(cc4c3c2)oc2ccc(C#N)cc25)c(-n2c3ccccc3c3ccccc32)c1]

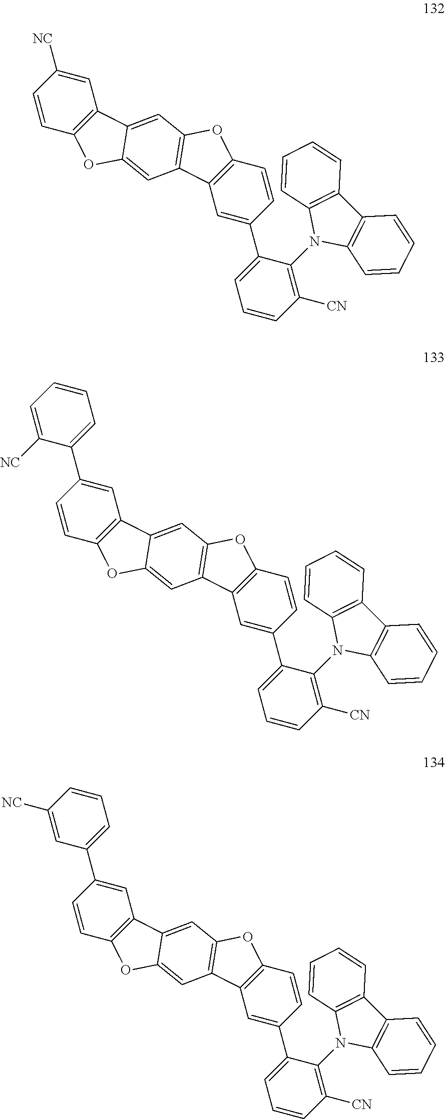 [SMILES: N#Cc1ccc2oc3cc4c(cc3c2c1)oc1ccc(-c2cccc(C#N)c2-n2c3ccccc3c3ccccc32)cc14 ; N#Cc1ccccc1-c1ccc2oc3cc4c(cc3c2c1)oc1ccc(-c2cccc(C#N)c2-n2c3ccccc3c3ccccc32)cc14 ; N#Cc1cccc(-c2ccc3oc4cc5c(cc4c3c2)oc2ccc(-c3cccc(C#N)c3-n3c4ccccc4c4ccccc43)cc25)c1]

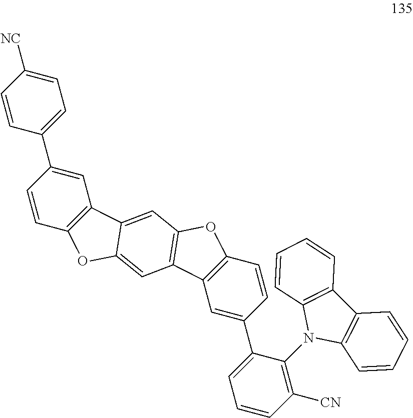 [SMILES: N#Cc1ccc(-c2ccc3oc4cc5c(cc4c3c2)oc2ccc(-c3cccc(C#N)c3-n3c4ccccc4c4ccccc43)cc25)cc1]

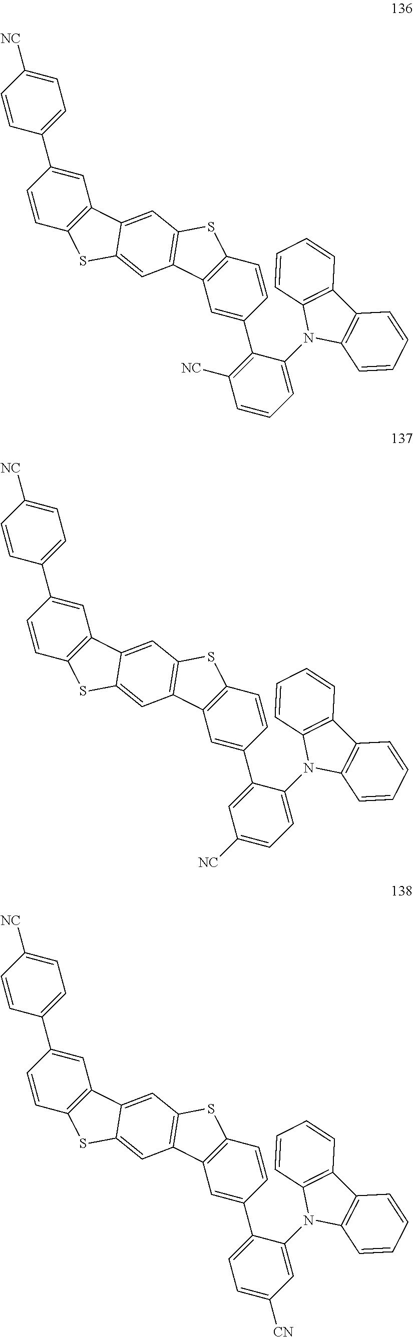 [SMILES: N#Cc1ccc(-c2ccc3sc4cc5c(cc4c3c2)sc2ccc(-c3c(C#N)cccc3-n3c4ccccc4c4ccccc43)cc25)cc1 ; N#Cc1ccc(-c2ccc3sc4cc5c(cc4c3c2)sc2ccc(-c3cc(C#N)ccc3-n3c4ccccc4c4ccccc43)cc25)cc1 ; N#Cc1ccc(-c2ccc3sc4cc5c(cc4c3c2)sc2ccc(-c3ccc(C#N)cc3-n3c4ccccc4c4ccccc43)cc25)cc1]

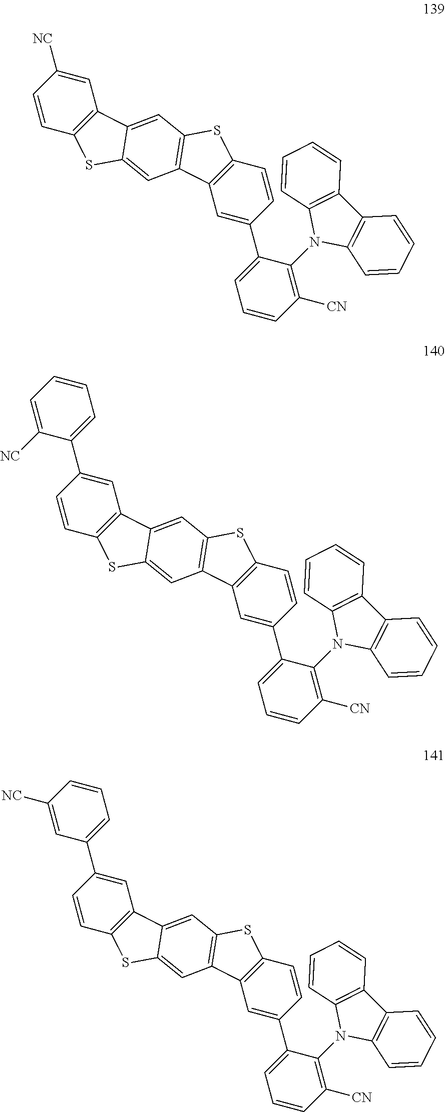 [SMILES: N#Cc1ccc2sc3cc4c(cc3c2c1)sc1ccc(-c2cccc(C#N)c2-n2c3ccccc3c3ccccc32)cc14 ; N#Cc1ccccc1-c1ccc2sc3cc4c(cc3c2c1)sc1ccc(-c2cccc(C#N)c2-n2c3ccccc3c3ccccc32)cc14 ; N#Cc1cccc(-c2ccc3sc4cc5c(cc4c3c2)sc2ccc(-c3cccc(C#N)c3-n3c4ccccc4c4ccccc43)cc25)c1]

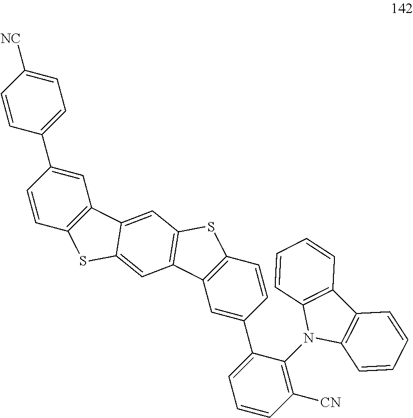 [SMILES: N#Cc1ccc(-c2ccc3sc4cc5c(cc4c3c2)sc2ccc(-c3cccc(C#N)c3-n3c4ccccc4c4ccccc43)cc25)cc1]

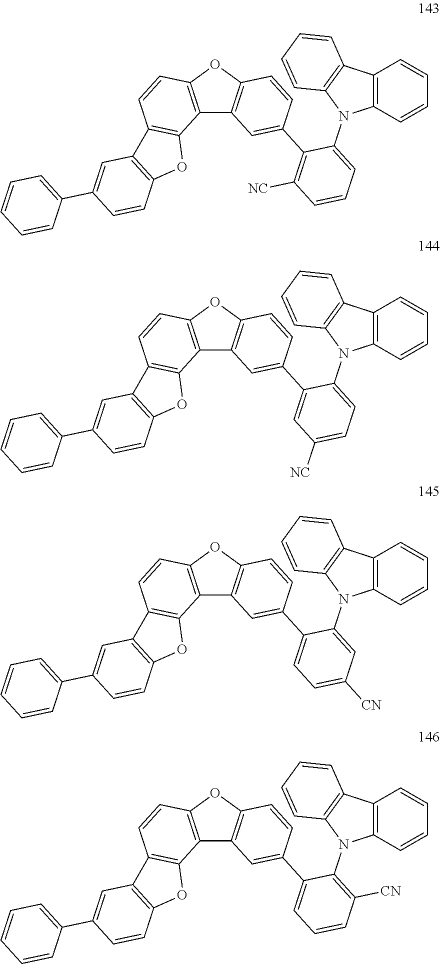 [SMILES: N#Cc1cccc(-n2c3ccccc3c3ccccc32)c1-c1ccc2oc3ccc4c5cc(-c6ccccc6)ccc5oc4c3c2c1 ; N#Cc1ccc(-n2c3ccccc3c3ccccc32)c(-c2ccc3oc4ccc5c6cc(-c7ccccc7)ccc6oc5c4c3c2)c1 ; N#Cc1ccc(-c2ccc3oc4ccc5c6cc(-c7ccccc7)ccc6oc5c4c3c2)c(-n2c3ccccc3c3ccccc32)c1 ; N#Cc1cccc(-c2ccc3oc4ccc5c6cc(-c7ccccc7)ccc6oc5c4c3c2)c1-n1c2ccccc2c2ccccc21]

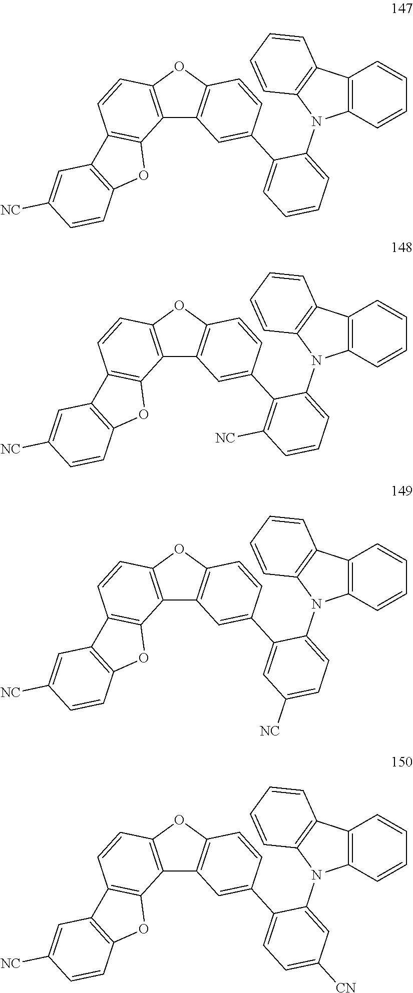 [SMILES: N#Cc1ccc2oc3c(ccc4oc5ccc(-c6ccccc6-n6c7ccccc7c7ccccc76)cc5c43)c2c1 ; N#Cc1ccc2oc3c(ccc4oc5ccc(-c6c(C#N)cccc6-n6c7ccccc7c7ccccc76)cc5c43)c2c1 ; N#Cc1ccc(-n2c3ccccc3c3ccccc32)c(-c2ccc3oc4ccc5c6cc(C#N)ccc6oc5c4c3c2)c1 ; N#Cc1ccc(-c2ccc3oc4ccc5c6cc(C#N)ccc6oc5c4c3c2)c(-n2c3ccccc3c3ccccc32)c1]

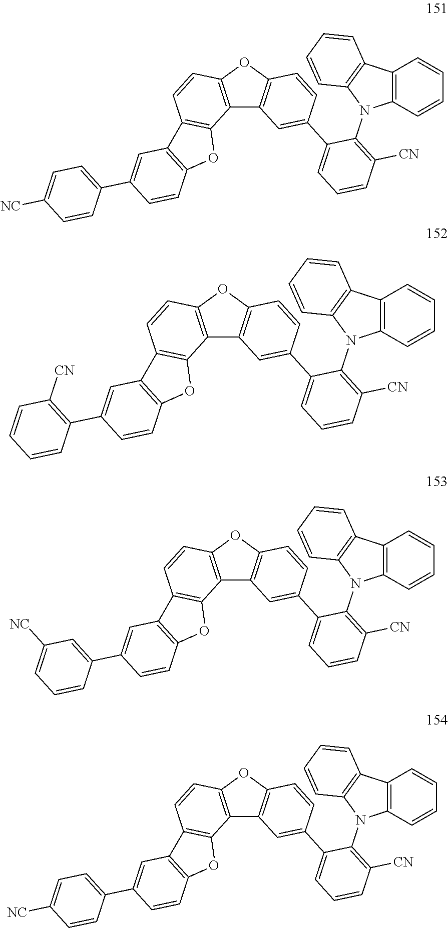 [SMILES: N#Cc1ccc(-c2ccc3oc4c(ccc5oc6ccc(-c7cccc(C#N)c7-n7c8ccccc8c8ccccc87)cc6c54)c3c2)cc1 ; N#Cc1ccccc1-c1ccc2oc3c(ccc4oc5ccc(-c6cccc(C#N)c6-n6c7ccccc7c7ccccc76)cc5c43)c2c1 ; N#Cc1cccc(-c2ccc3oc4c(ccc5oc6ccc(-c7cccc(C#N)c7-n7c8ccccc8c8ccccc87)cc6c54)c3c2)c1 ; N#Cc1ccc(-c2ccc3oc4c(ccc5oc6ccc(-c7cccc(C#N)c7-n7c8ccccc8c8ccccc87)cc6c54)c3c2)cc1]

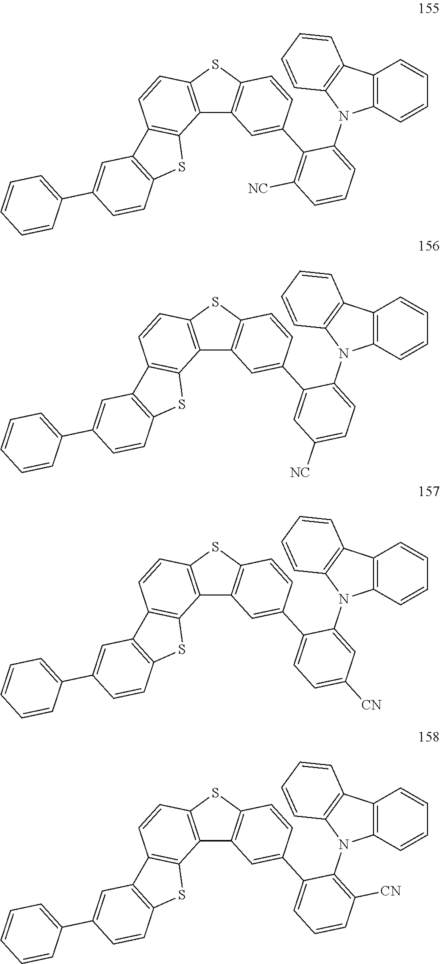 [SMILES: N#Cc1cccc(-n2c3ccccc3c3ccccc32)c1-c1ccc2sc3ccc4c5cc(-c6ccccc6)ccc5sc4c3c2c1 ; N#Cc1ccc(-n2c3ccccc3c3ccccc32)c(-c2ccc3sc4ccc5c6cc(-c7ccccc7)ccc6sc5c4c3c2)c1 ; N#Cc1ccc(-c2ccc3sc4ccc5c6cc(-c7ccccc7)ccc6sc5c4c3c2)c(-n2c3ccccc3c3ccccc32)c1 ; N#Cc1cccc(-c2ccc3sc4ccc5c6cc(-c7ccccc7)ccc6sc5c4c3c2)c1-n1c2ccccc2c2ccccc21]

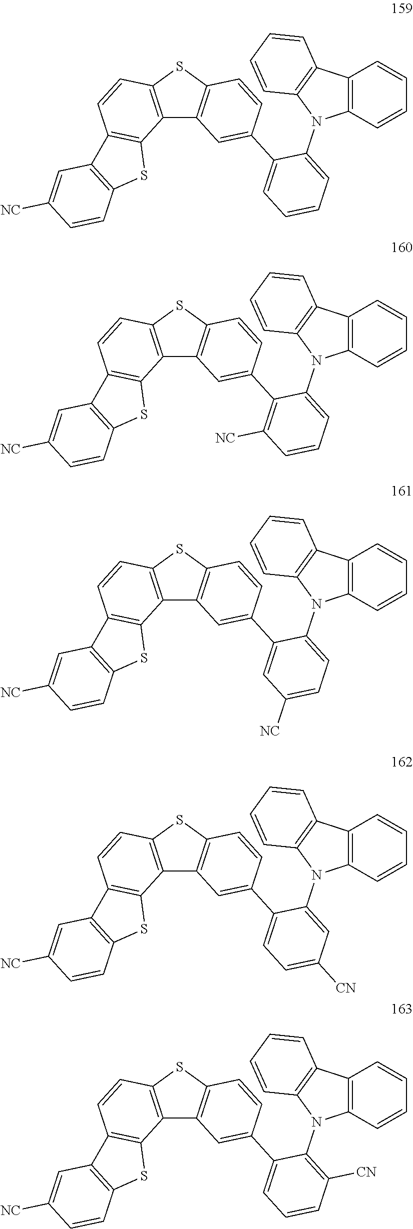 [SMILES: N#Cc1ccc2sc3c(ccc4sc5ccc(-c6ccccc6-n6c7ccccc7c7ccccc76)cc5c43)c2c1 ; N#Cc1ccc2sc3c(ccc4sc5ccc(-c6c(C#N)cccc6-n6c7ccccc7c7ccccc76)cc5c43)c2c1 ; N#Cc1ccc(-n2c3ccccc3c3ccccc32)c(-c2ccc3sc4ccc5c6cc(C#N)ccc6sc5c4c3c2)c1 ; N#Cc1ccc(-c2ccc3sc4ccc5c6cc(C#N)ccc6sc5c4c3c2)c(-n2c3ccccc3c3ccccc32)c1 ; N#Cc1ccc2sc3c(ccc4sc5ccc(-c6cccc(C#N)c6-n6c7ccccc7c7ccccc76)cc5c43)c2c1]

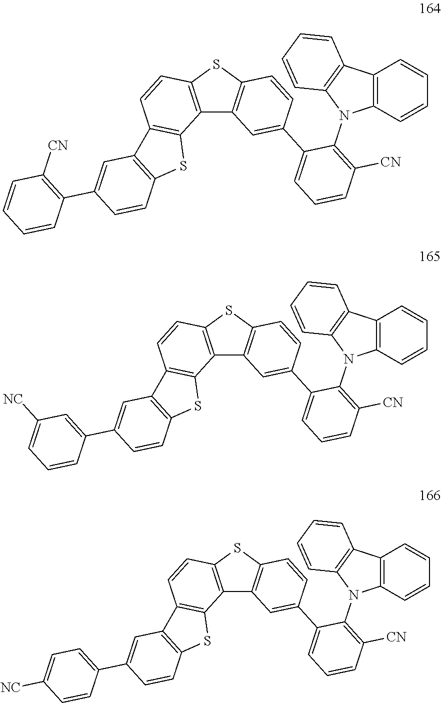 [SMILES: N#Cc1ccccc1-c1ccc2sc3c(ccc4sc5ccc(-c6cccc(C#N)c6-n6c7ccccc7c7ccccc76)cc5c43)c2c1 ; N#Cc1cccc(-c2ccc3sc4c(ccc5sc6ccc(-c7cccc(C#N)c7-n7c8ccccc8c8ccccc87)cc6c54)c3c2)c1 ; N#Cc1ccc(-c2ccc3sc4c(ccc5sc6ccc(-c7cccc(C#N)c7-n7c8ccccc8c8ccccc87)cc6c54)c3c2)cc1]

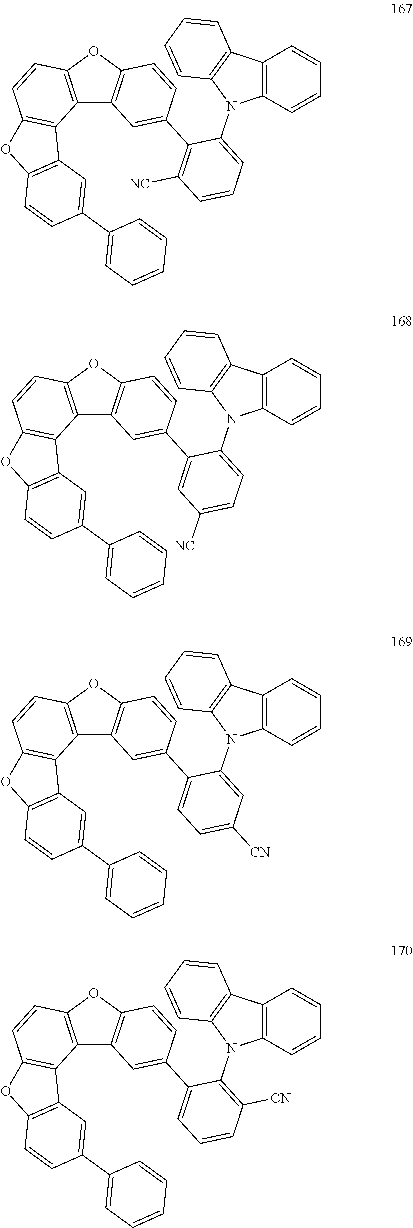 [SMILES: N#Cc1cccc(-n2c3ccccc3c3ccccc32)c1-c1ccc2oc3ccc4oc5ccc(-c6ccccc6)cc5c4c3c2c1 ; N#Cc1ccc(-n2c3ccccc3c3ccccc32)c(-c2ccc3oc4ccc5oc6ccc(-c7ccccc7)cc6c5c4c3c2)c1 ; N#Cc1ccc(-c2ccc3oc4ccc5oc6ccc(-c7ccccc7)cc6c5c4c3c2)c(-n2c3ccccc3c3ccccc32)c1 ; N#Cc1cccc(-c2ccc3oc4ccc5oc6ccc(-c7ccccc7)cc6c5c4c3c2)c1-n1c2ccccc2c2ccccc21]

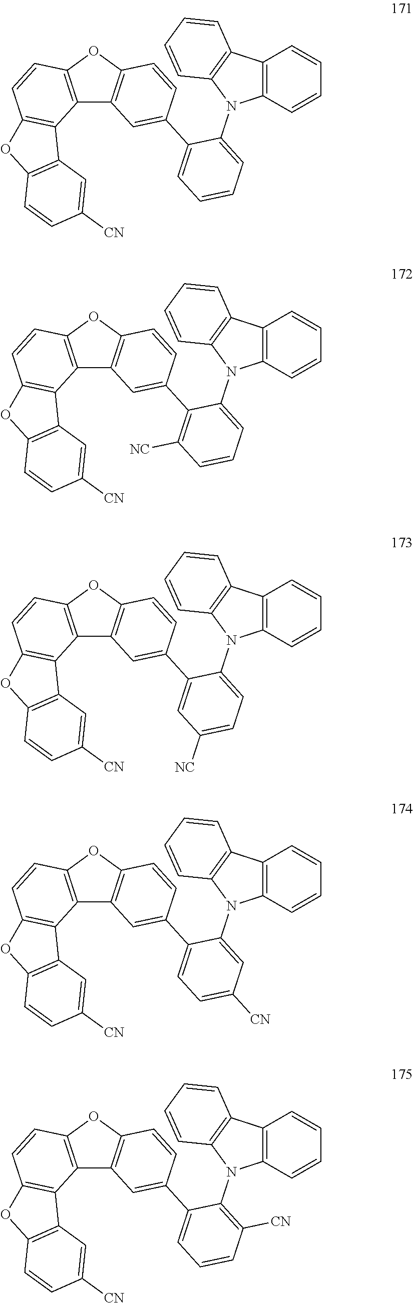 [SMILES: N#Cc1ccc2oc3ccc4oc5ccc(-c6ccccc6-n6c7ccccc7c7ccccc76)cc5c4c3c2c1 ; N#Cc1ccc2oc3ccc4oc5ccc(-c6c(C#N)cccc6-n6c7ccccc7c7ccccc76)cc5c4c3c2c1 ; N#Cc1ccc(-n2c3ccccc3c3ccccc32)c(-c2ccc3oc4ccc5oc6ccc(C#N)cc6c5c4c3c2)c1 ; N#Cc1ccc(-c2ccc3oc4ccc5oc6ccc(C#N)cc6c5c4c3c2)c(-n2c3ccccc3c3ccccc32)c1 ; N#Cc1ccc2oc3ccc4oc5ccc(-c6cccc(C#N)c6-n6c7ccccc7c7ccccc76)cc5c4c3c2c1]

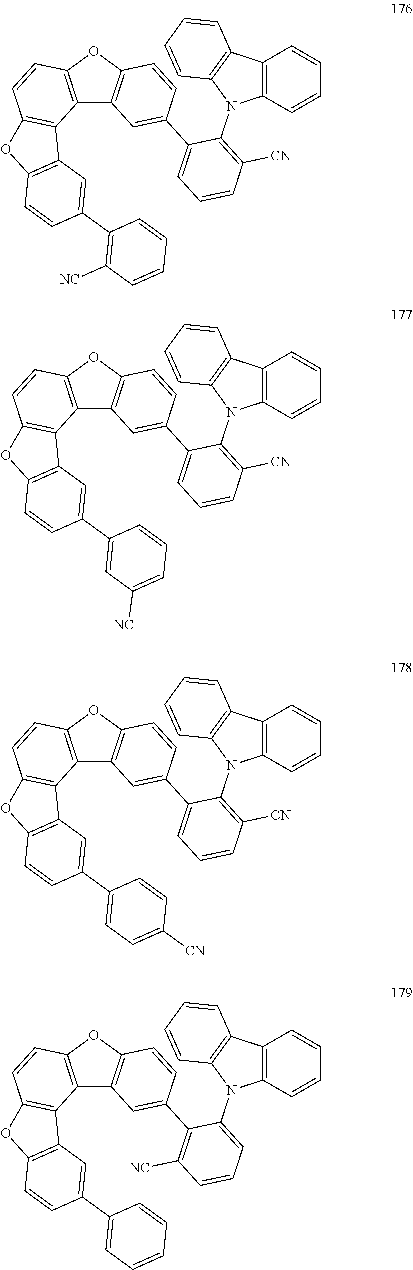 [SMILES: N#Cc1ccccc1-c1ccc2oc3ccc4oc5ccc(-c6cccc(C#N)c6-n6c7ccccc7c7ccccc76)cc5c4c3c2c1 ; N#Cc1cccc(-c2ccc3oc4ccc5oc6ccc(-c7cccc(C#N)c7-n7c8ccccc8c8ccccc87)cc6c5c4c3c2)c1 ; N#Cc1ccc(-c2ccc3oc4ccc5oc6ccc(-c7cccc(C#N)c7-n7c8ccccc8c8ccccc87)cc6c5c4c3c2)cc1 ; N#Cc1cccc(-n2c3ccccc3c3ccccc32)c1-c1ccc2oc3ccc4oc5ccc(-c6ccccc6)cc5c4c3c2c1]

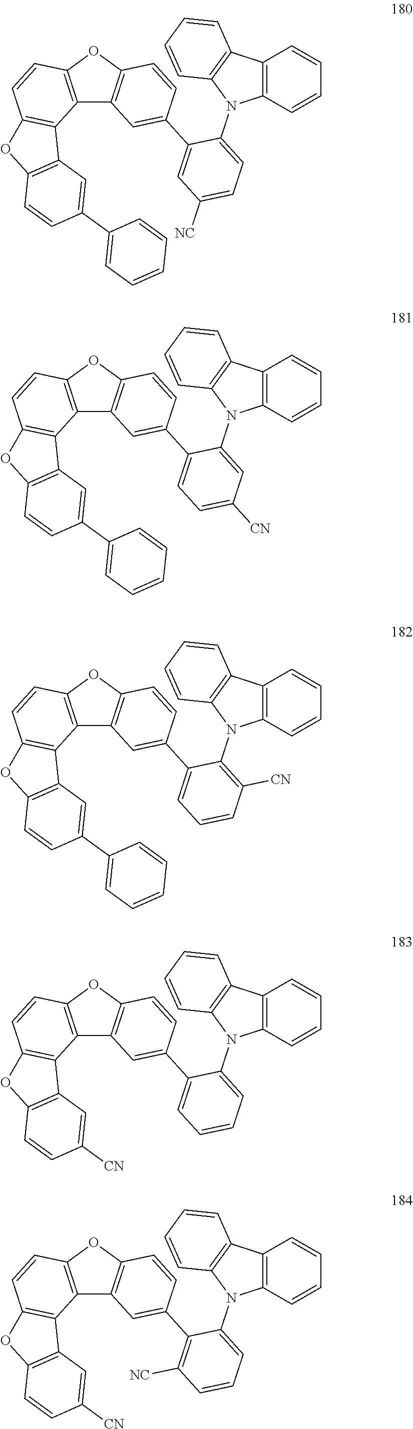 [SMILES: N#Cc1ccc(-n2c3ccccc3c3ccccc32)c(-c2ccc3oc4ccc5oc6ccc(-c7ccccc7)cc6c5c4c3c2)c1 ; N#Cc1ccc(-c2ccc3oc4ccc5oc6ccc(-c7ccccc7)cc6c5c4c3c2)c(-n2c3ccccc3c3ccccc32)c1 ; N#Cc1cccc(-c2ccc3oc4ccc5oc6ccc(-c7ccccc7)cc6c5c4c3c2)c1-n1c2ccccc2c2ccccc21 ; N#Cc1ccc2oc3ccc4oc5ccc(-c6ccccc6-n6c7ccccc7c7ccccc76)cc5c4c3c2c1 ; N#Cc1ccc2oc3ccc4oc5ccc(-c6c(C#N)cccc6-n6c7ccccc7c7ccccc76)cc5c4c3c2c1]

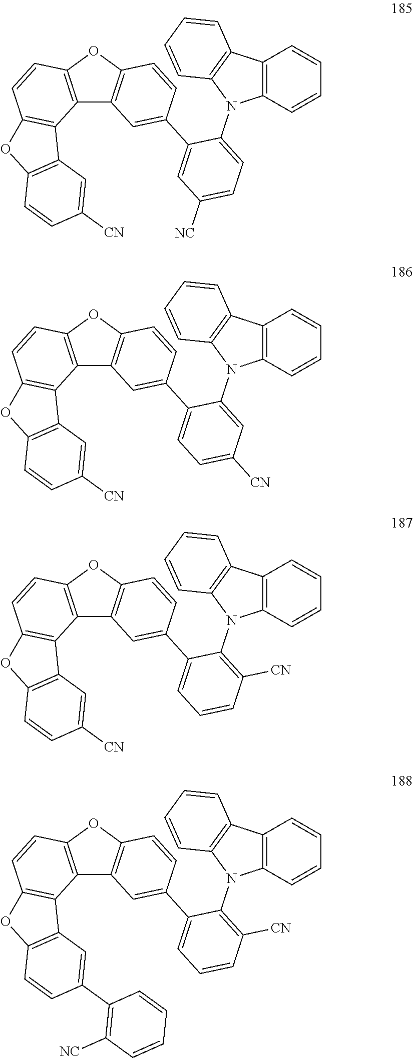 [SMILES: N#Cc1ccc(-n2c3ccccc3c3ccccc32)c(-c2ccc3oc4ccc5oc6ccc(C#N)cc6c5c4c3c2)c1 ; N#Cc1ccc(-c2ccc3oc4ccc5oc6ccc(C#N)cc6c5c4c3c2)c(-n2c3ccccc3c3ccccc32)c1 ; N#Cc1ccc2oc3ccc4oc5ccc(-c6cccc(C#N)c6-n6c7ccccc7c7ccccc76)cc5c4c3c2c1 ; N#Cc1ccccc1-c1ccc2oc3ccc4oc5ccc(-c6cccc(C#N)c6-n6c7ccccc7c7ccccc76)cc5c4c3c2c1]

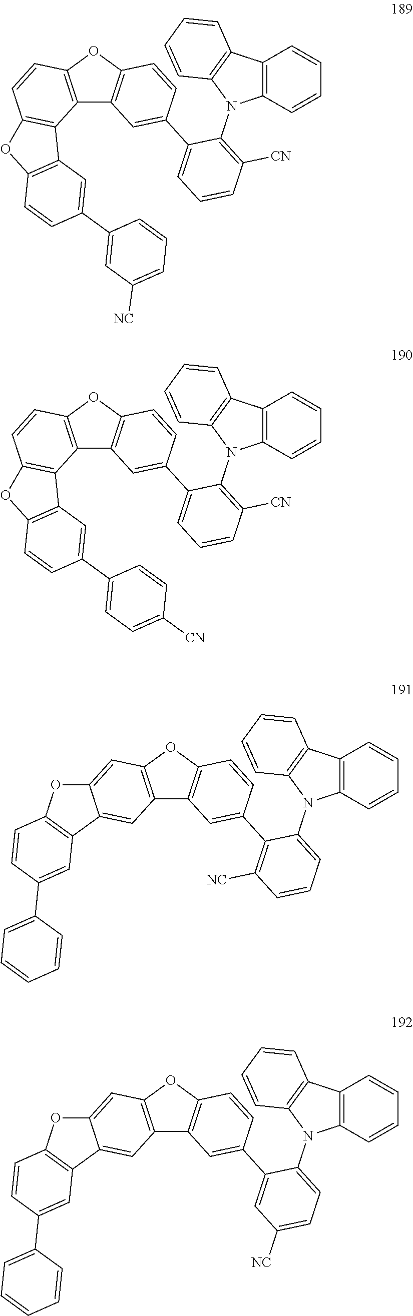 [SMILES: N#Cc1cccc(-c2ccc3oc4ccc5oc6ccc(-c7cccc(C#N)c7-n7c8ccccc8c8ccccc87)cc6c5c4c3c2)c1 ; N#Cc1ccc(-c2ccc3oc4ccc5oc6ccc(-c7cccc(C#N)c7-n7c8ccccc8c8ccccc87)cc6c5c4c3c2)cc1 ; N#Cc1cccc(-n2c3ccccc3c3ccccc32)c1-c1ccc2oc3cc4oc5ccc(-c6ccccc6)cc5c4cc3c2c1 ; N#Cc1ccc(-n2c3ccccc3c3ccccc32)c(-c2ccc3oc4cc5oc6ccc(-c7ccccc7)cc6c5cc4c3c2)c1]

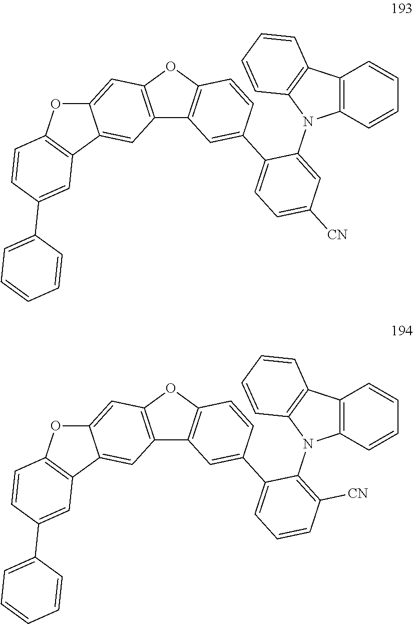 [SMILES: N#Cc1ccc(-c2ccc3oc4cc5oc6ccc(-c7ccccc7)cc6c5cc4c3c2)c(-n2c3ccccc3c3ccccc32)c1 ; N#Cc1cccc(-c2ccc3oc4cc5oc6ccc(-c7ccccc7)cc6c5cc4c3c2)c1-n1c2ccccc2c2ccccc21]

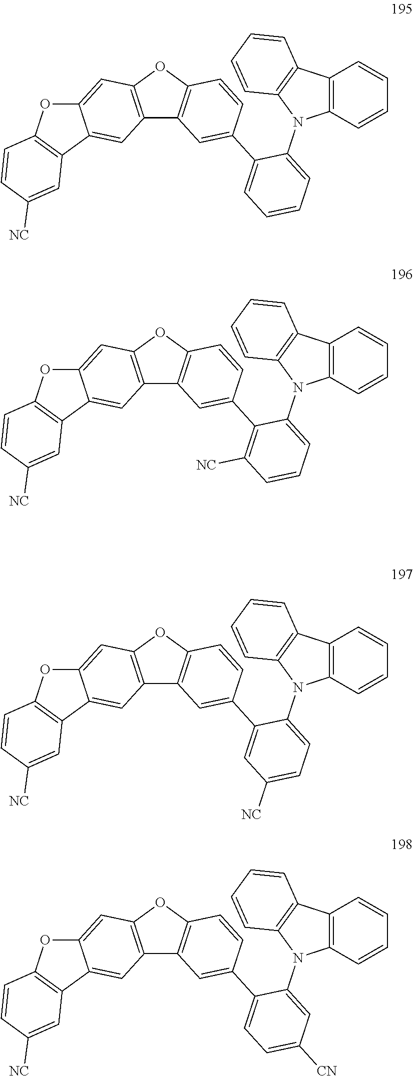 [SMILES: N#Cc1ccc2oc3cc4oc5ccc(-c6ccccc6-n6c7ccccc7c7ccccc76)cc5c4cc3c2c1 ; N#Cc1ccc2oc3cc4oc5ccc(-c6c(C#N)cccc6-n6c7ccccc7c7ccccc76)cc5c4cc3c2c1 ; N#Cc1ccc(-n2c3ccccc3c3ccccc32)c(-c2ccc3oc4cc5oc6ccc(C#N)cc6c5cc4c3c2)c1 ; N#Cc1ccc(-c2ccc3oc4cc5oc6ccc(C#N)cc6c5cc4c3c2)c(-n2c3ccccc3c3ccccc32)c1]

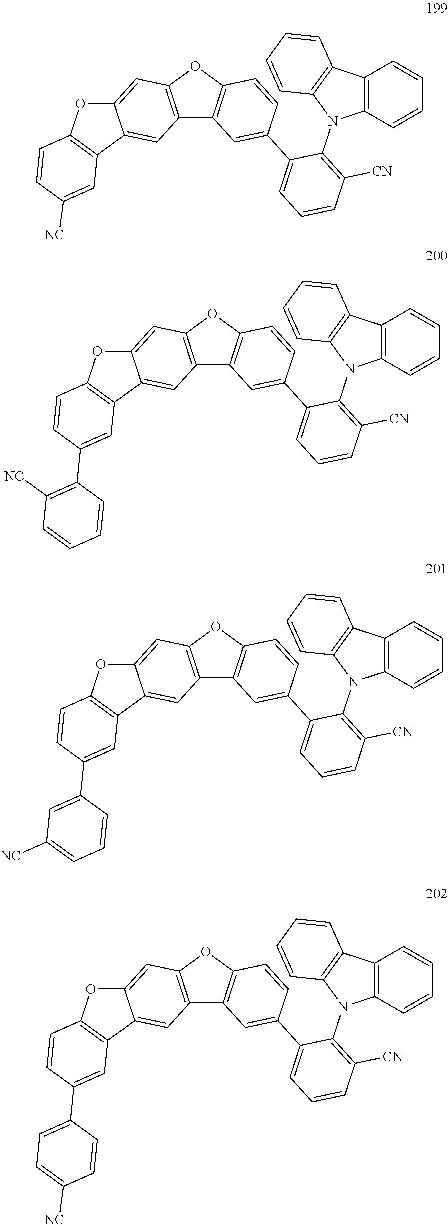 [SMILES: N#Cc1ccc2oc3cc4oc5ccc(-c6cccc(C#N)c6-n6c7ccccc7c7ccccc76)cc5c4cc3c2c1 ; N#Cc1ccccc1-c1ccc2oc3cc4oc5ccc(-c6cccc(C#N)c6-n6c7ccccc7c7ccccc76)cc5c4cc3c2c1 ; N#Cc1cccc(-c2ccc3oc4cc5oc6ccc(-c7cccc(C#N)c7-n7c8ccccc8c8ccccc87)cc6c5cc4c3c2)c1 ; N#Cc1ccc(-c2ccc3oc4cc5oc6ccc(-c7cccc(C#N)c7-n7c8ccccc8c8ccccc87)cc6c5cc4c3c2)cc1]

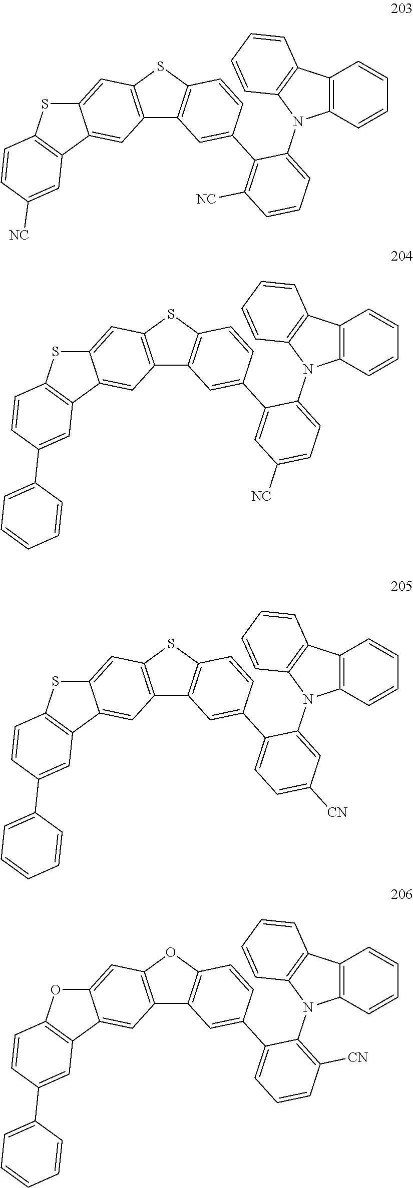 [SMILES: N#Cc1ccc2sc3cc4sc5ccc(-c6c(C#N)cccc6-n6c7ccccc7c7ccccc76)cc5c4cc3c2c1 ; N#Cc1ccc(-n2c3ccccc3c3ccccc32)c(-c2ccc3sc4cc5sc6ccc(-c7ccccc7)cc6c5cc4c3c2)c1 ; N#Cc1ccc(-c2ccc3sc4cc5sc6ccc(-c7ccccc7)cc6c5cc4c3c2)c(-n2c3ccccc3c3ccccc32)c1 ; N#Cc1cccc(-c2ccc3oc4cc5oc6ccc(-c7ccccc7)cc6c5cc4c3c2)c1-n1c2ccccc2c2ccccc21]

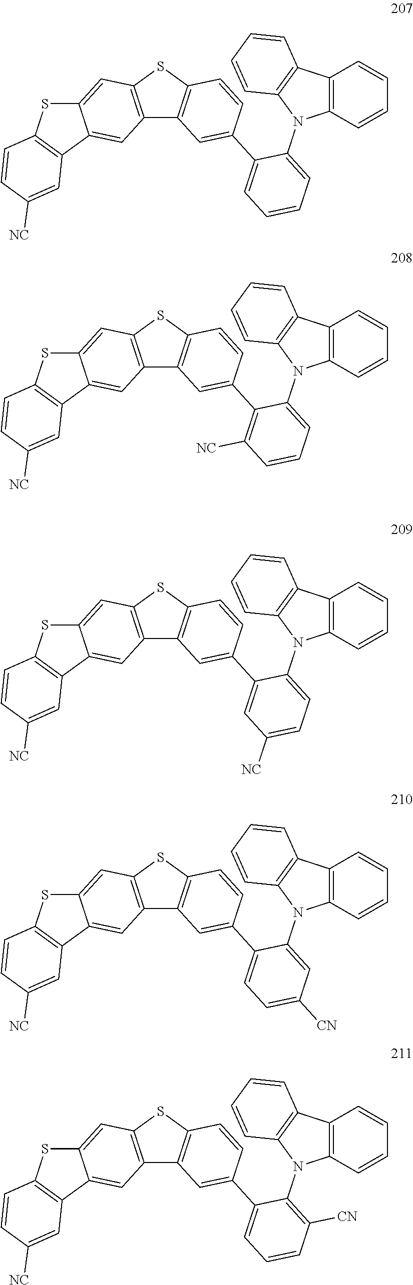 [SMILES: N#Cc1ccc2sc3cc4sc5ccc(-c6ccccc6-n6c7ccccc7c7ccccc76)cc5c4cc3c2c1 ; N#Cc1ccc2sc3cc4sc5ccc(-c6c(C#N)cccc6-n6c7ccccc7c7ccccc76)cc5c4cc3c2c1 ; N#Cc1ccc(-n2c3ccccc3c3ccccc32)c(-c2ccc3sc4cc5sc6ccc(C#N)cc6c5cc4c3c2)c1 ; N#Cc1ccc(-c2ccc3sc4cc5sc6ccc(C#N)cc6c5cc4c3c2)c(-n2c3ccccc3c3ccccc32)c1 ; N#Cc1ccc2sc3cc4sc5ccc(-c6cccc(C#N)c6-n6c7ccccc7c7ccccc76)cc5c4cc3c2c1]

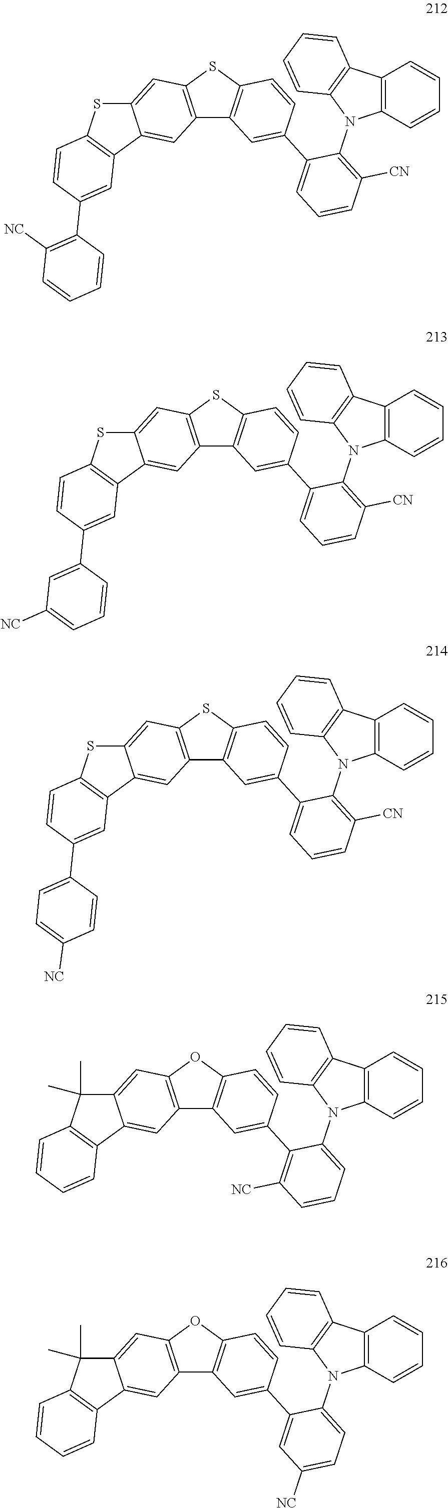 [SMILES: N#Cc1ccccc1-c1ccc2sc3cc4sc5ccc(-c6cccc(C#N)c6-n6c7ccccc7c7ccccc76)cc5c4cc3c2c1 ; N#Cc1cccc(-c2ccc3sc4cc5sc6ccc(-c7cccc(C#N)c7-n7c8ccccc8c8ccccc87)cc6c5cc4c3c2)c1 ; N#Cc1ccc(-c2ccc3sc4cc5sc6ccc(-c7cccc(C#N)c7-n7c8ccccc8c8ccccc87)cc6c5cc4c3c2)cc1 ; CC1(C)c2ccccc2-c2cc3c(cc21)oc1ccc(-c2c(C#N)cccc2-n2c4ccccc4c4ccccc42)cc13 ; CC1(C)c2ccccc2-c2cc3c(cc21)oc1ccc(-c2cc(C#N)ccc2-n2c4ccccc4c4ccccc42)cc13]

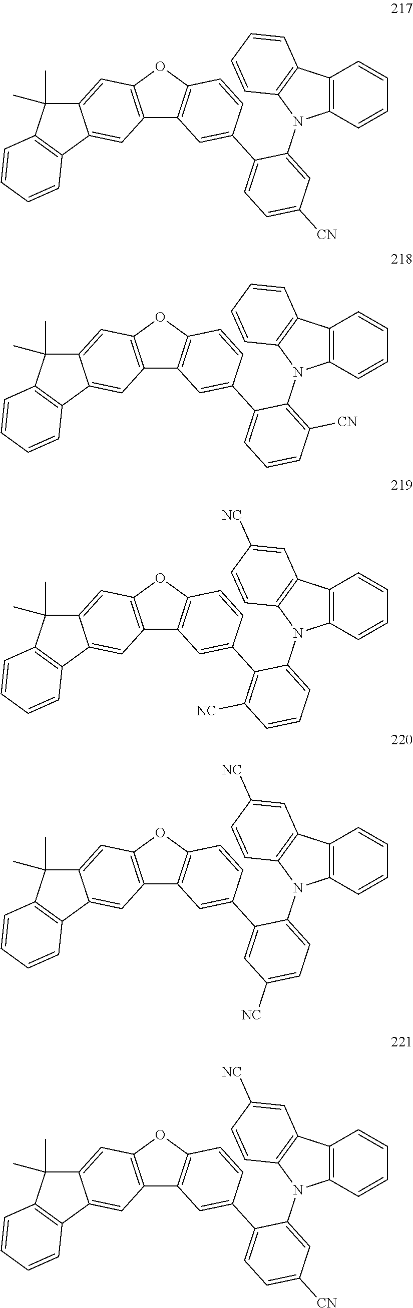 [SMILES: CC1(C)c2ccccc2-c2cc3c(cc21)oc1ccc(-c2ccc(C#N)cc2-n2c4ccccc4c4ccccc42)cc13 ; CC1(C)c2ccccc2-c2cc3c(cc21)oc1ccc(-c2cccc(C#N)c2-n2c4ccccc4c4ccccc42)cc13 ; CC1(C)c2ccccc2-c2cc3c(cc21)oc1ccc(-c2c(C#N)cccc2-n2c4ccccc4c4cc(C#N)ccc42)cc13 ; CC1(C)c2ccccc2-c2cc3c(cc21)oc1ccc(-c2cc(C#N)ccc2-n2c4ccccc4c4cc(C#N)ccc42)cc13 ; CC1(C)c2ccccc2-c2cc3c(cc21)oc1ccc(-c2ccc(C#N)cc2-n2c4ccccc4c4cc(C#N)ccc42)cc13]

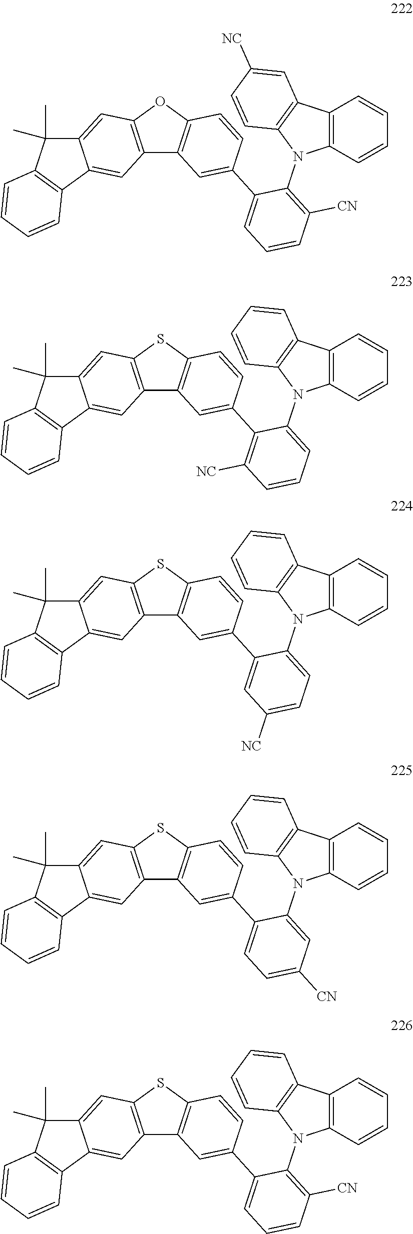

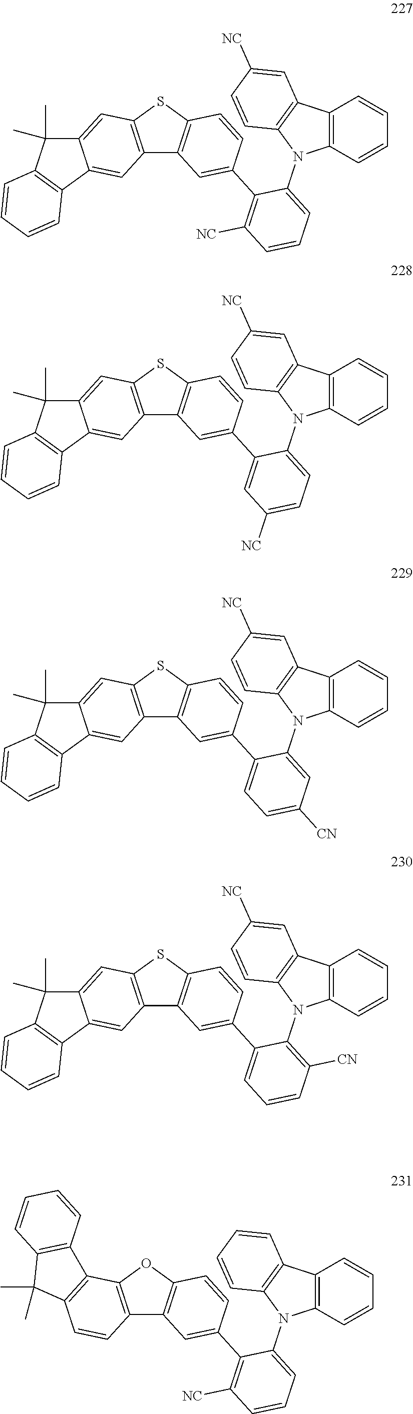 [SMILES: CC1(C)c2ccccc2-c2cc3c(cc21)sc1ccc(-c2c(C#N)cccc2-n2c4ccccc4c4cc(C#N)ccc42)cc13 ; CC1(C)c2ccccc2-c2cc3c(cc21)sc1ccc(-c2cc(C#N)ccc2-n2c4ccccc4c4cc(C#N)ccc42)cc13 ; CC1(C)c2ccccc2-c2cc3c(cc21)sc1ccc(-c2ccc(C#N)cc2-n2c4ccccc4c4cc(C#N)ccc42)cc13 ; CC1(C)c2ccccc2-c2cc3c(cc21)sc1ccc(-c2cccc(C#N)c2-n2c4ccccc4c4cc(C#N)ccc42)cc13 ; CC1(C)c2ccccc2-c2c1ccc1c2oc2ccc(-c3c(C#N)cccc3-n3c4ccccc4c4ccccc43)cc21]

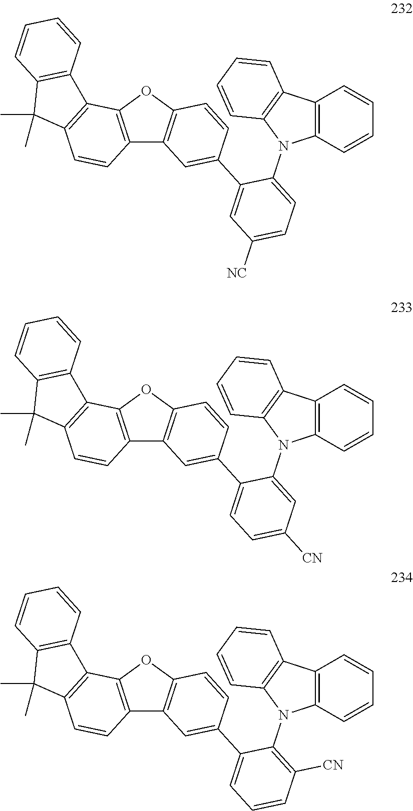 [SMILES: CC1(C)c2ccccc2-c2c1ccc1c2oc2ccc(-c3cc(C#N)ccc3-n3c4ccccc4c4ccccc43)cc21 ; CC1(C)c2ccccc2-c2c1ccc1c2oc2ccc(-c3ccc(C#N)cc3-n3c4ccccc4c4ccccc43)cc21 ; CC1(C)c2ccccc2-c2c1ccc1c2oc2ccc(-c3cccc(C#N)c3-n3c4ccccc4c4ccccc43)cc21]

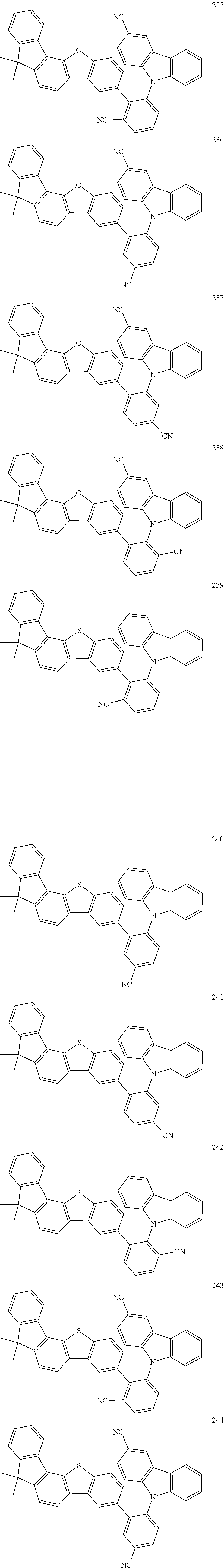

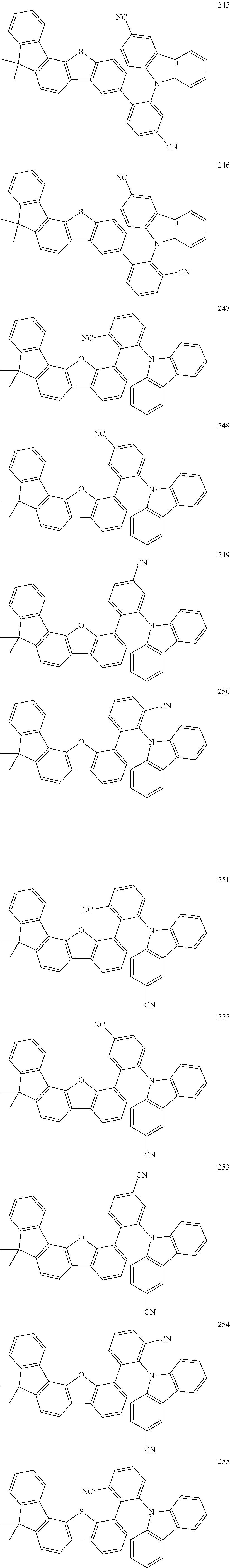

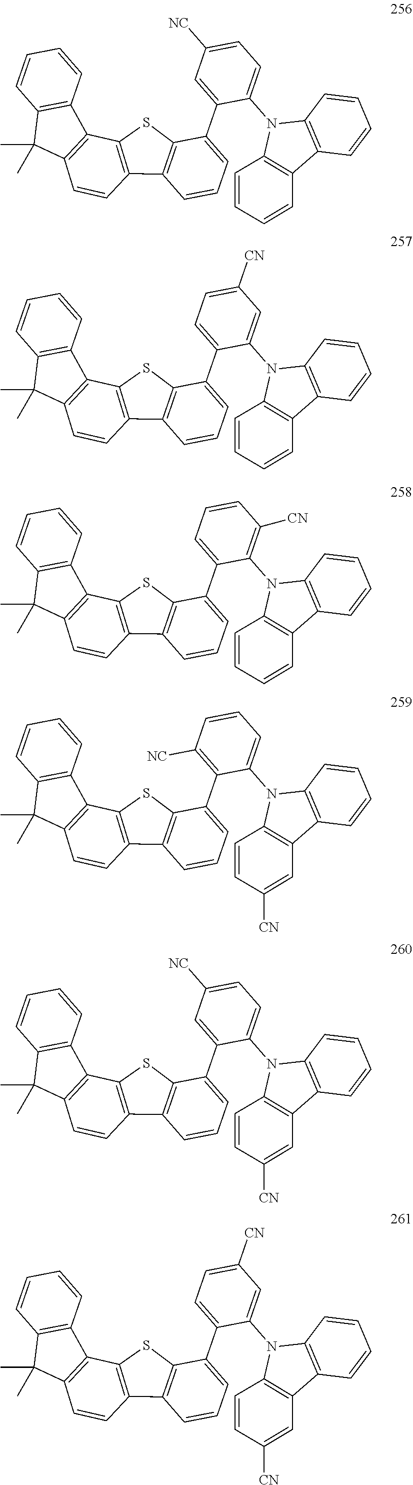

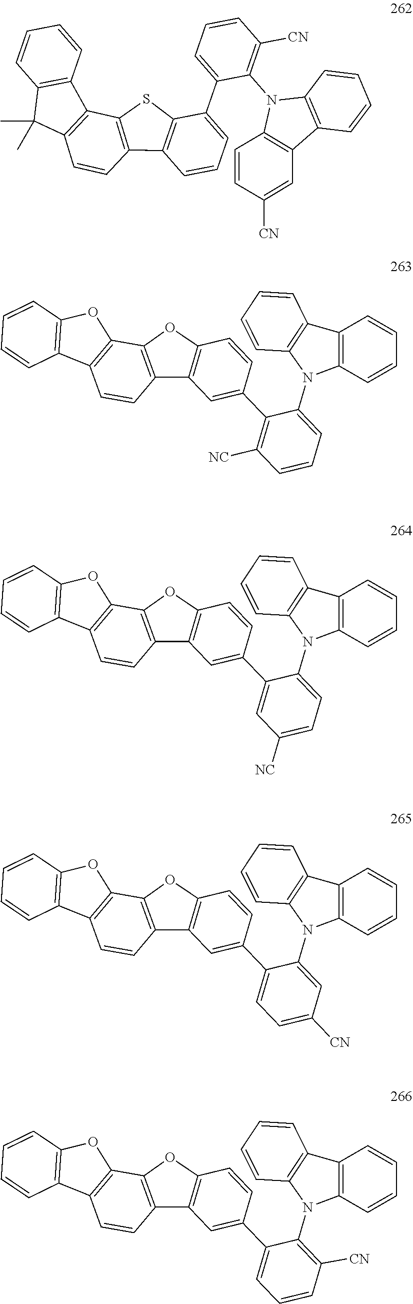 [SMILES: CC1(C)c2ccccc2-c2c1ccc1c2sc2c(-c3cccc(C#N)c3-n3c4ccccc4c4cc(C#N)ccc43)cccc21 ; N#Cc1cccc(-n2c3ccccc3c3ccccc32)c1-c1ccc2oc3c(ccc4c5ccccc5oc43)c2c1 ; N#Cc1ccc(-n2c3ccccc3c3ccccc32)c(-c2ccc3oc4c(ccc5c6ccccc6oc54)c3c2)c1 ; N#Cc1ccc(-c2ccc3oc4c(ccc5c6ccccc6oc54)c3c2)c(-n2c3ccccc3c3ccccc32)c1 ; N#Cc1cccc(-c2ccc3oc4c(ccc5c6ccccc6oc54)c3c2)c1-n1c2ccccc2c2ccccc21]

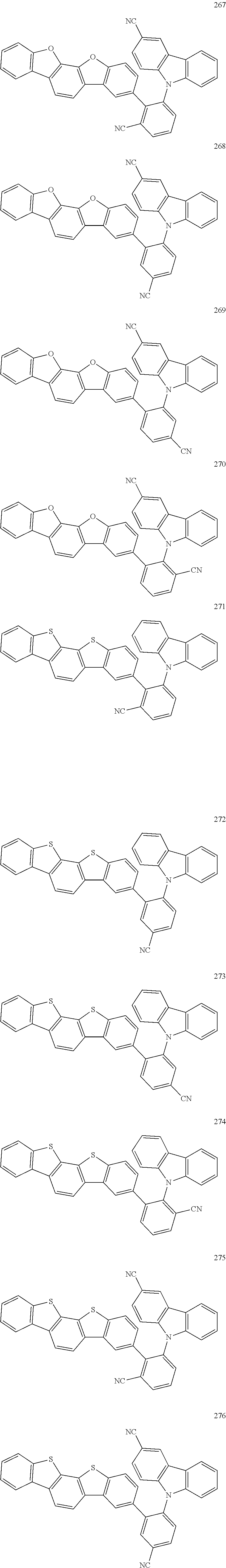

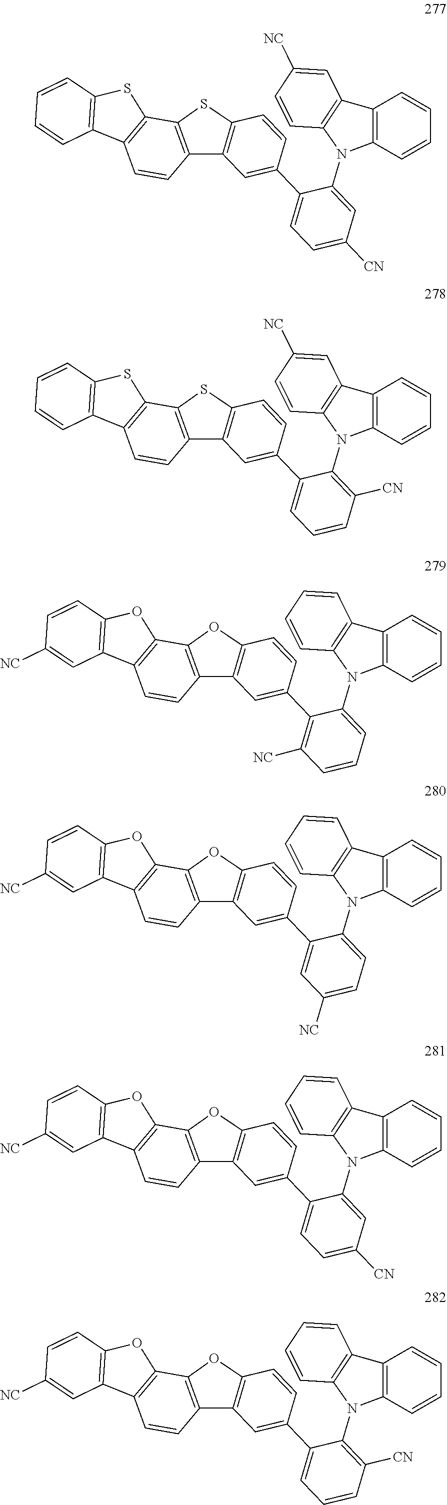 [SMILES: N#Cc1ccc(-c2ccc3sc4c(ccc5c6ccccc6sc54)c3c2)c(-n2c3ccccc3c3cc(C#N)ccc32)c1 ; N#Cc1ccc2c(c1)c1ccccc1n2-c1c(C#N)cccc1-c1ccc2sc3c(ccc4c5ccccc5sc43)c2c1 ; N#Cc1ccc2oc3c(ccc4c5cc(-c6c(C#N)cccc6-n6c7ccccc7c7ccccc76)ccc5oc43)c2c1 ; N#Cc1ccc(-n2c3ccccc3c3ccccc32)c(-c2ccc3oc4c(ccc5c6cc(C#N)ccc6oc54)c3c2)c1 ; N#Cc1ccc(-c2ccc3oc4c(ccc5c6cc(C#N)ccc6oc54)c3c2)c(-n2c3ccccc3c3ccccc32)c1 ; N#Cc1ccc2oc3c(ccc4c5cc(-c6cccc(C#N)c6-n6c7ccccc7c7ccccc76)ccc5oc43)c2c1]

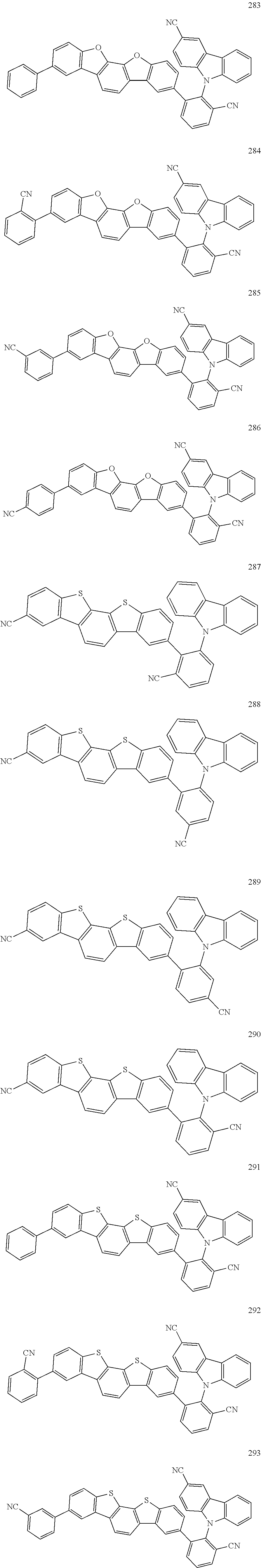

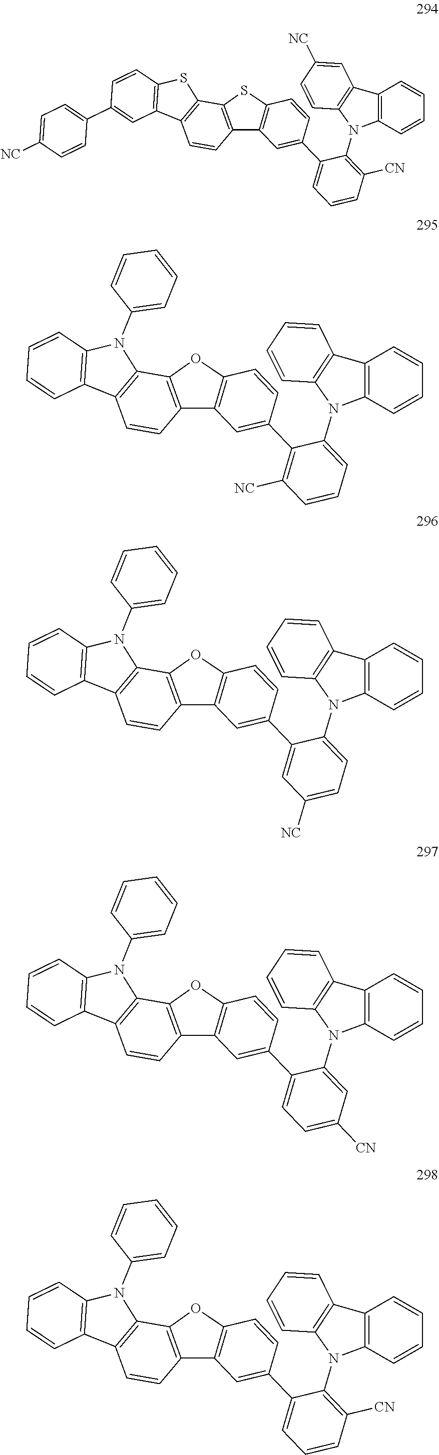 [SMILES: N#Cc1ccc(-c2ccc3sc4c(ccc5c6cc(-c7cccc(C#N)c7-n7c8ccccc8c8cc(C#N)ccc87)ccc6sc54)c3c2)cc1 ; N#Cc1cccc(-n2c3ccccc3c3ccccc32)c1-c1ccc2oc3c(ccc4c5ccccc5n(-c5ccccc5)c43)c2c1 ; N#Cc1ccc(-n2c3ccccc3c3ccccc32)c(-c2ccc3oc4c(ccc5c6ccccc6n(-c6ccccc6)c54)c3c2)c1 ; N#Cc1ccc(-c2ccc3oc4c(ccc5c6ccccc6n(-c6ccccc6)c54)c3c2)c(-n2c3ccccc3c3ccccc32)c1 ; N#Cc1cccc(-c2ccc3oc4c(ccc5c6ccccc6n(-c6ccccc6)c54)c3c2)c1-n1c2ccccc2c2ccccc21]

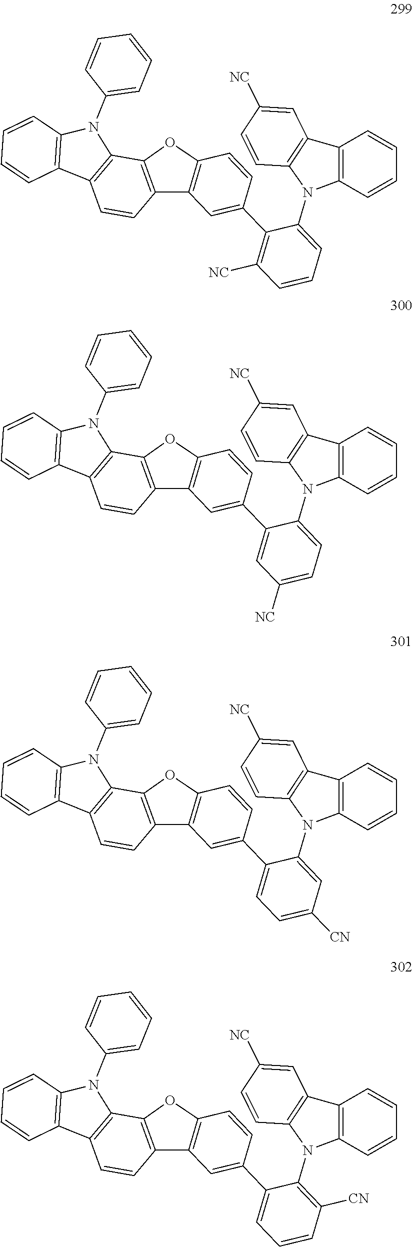 [SMILES: N#Cc1ccc2c(c1)c1ccccc1n2-c1cccc(C#N)c1-c1ccc2oc3c(ccc4c5ccccc5n(-c5ccccc5)c43)c2c1 ; N#Cc1ccc(-n2c3ccccc3c3cc(C#N)ccc32)c(-c2ccc3oc4c(ccc5c6ccccc6n(-c6ccccc6)c54)c3c2)c1 ; N#Cc1ccc(-c2ccc3oc4c(ccc5c6ccccc6n(-c6ccccc6)c54)c3c2)c(-n2c3ccccc3c3cc(C#N)ccc32)c1 ; N#Cc1ccc2c(c1)c1ccccc1n2-c1c(C#N)cccc1-c1ccc2oc3c(ccc4c5ccccc5n(-c5ccccc5)c43)c2c1]

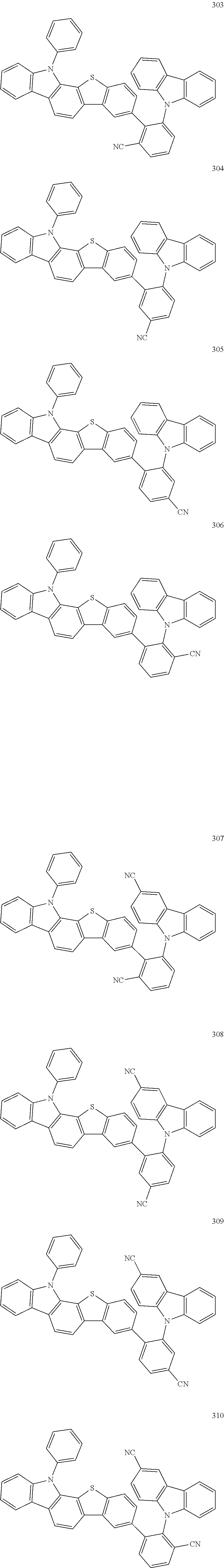

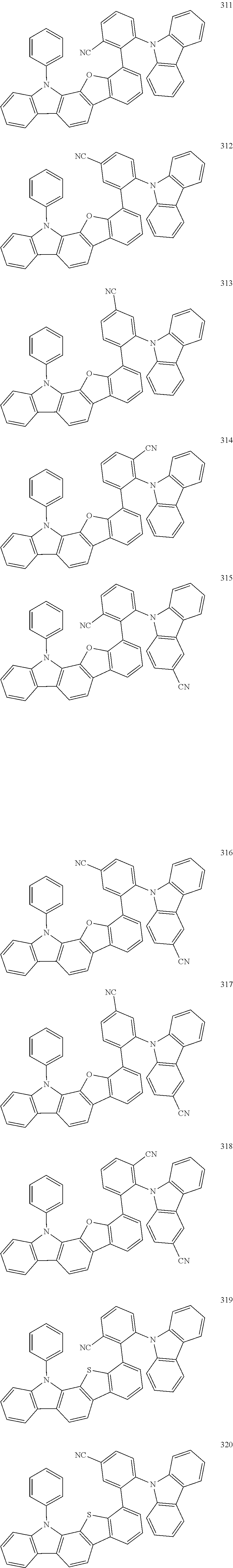

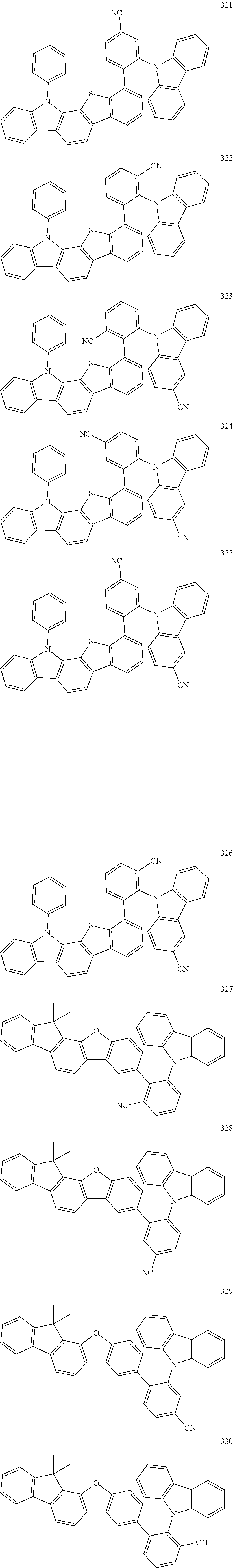

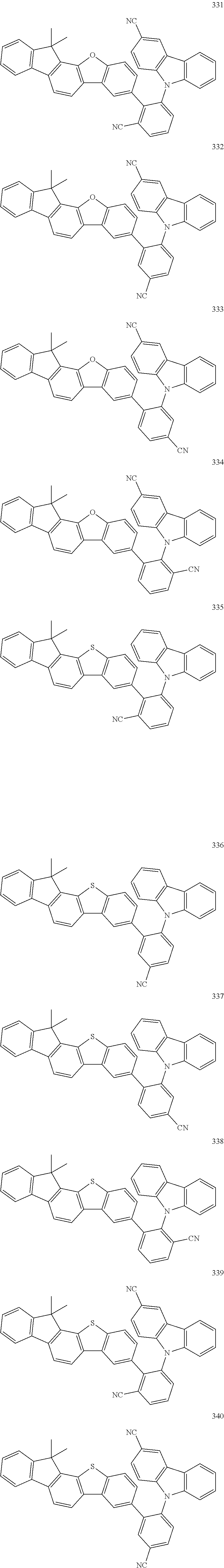

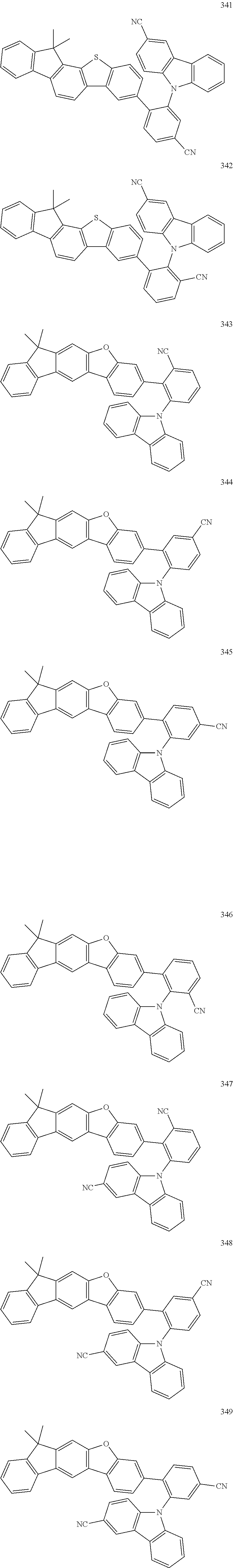

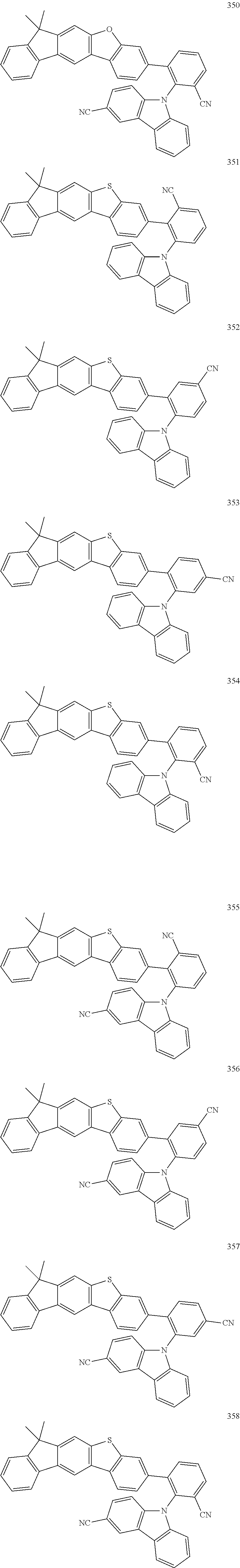

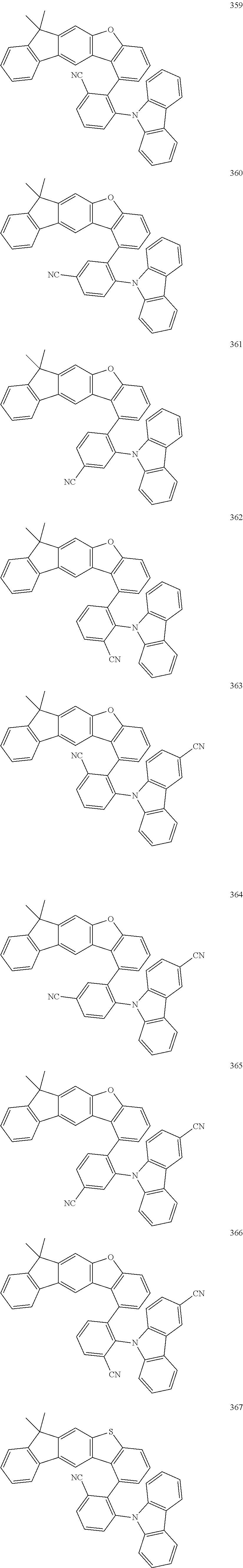

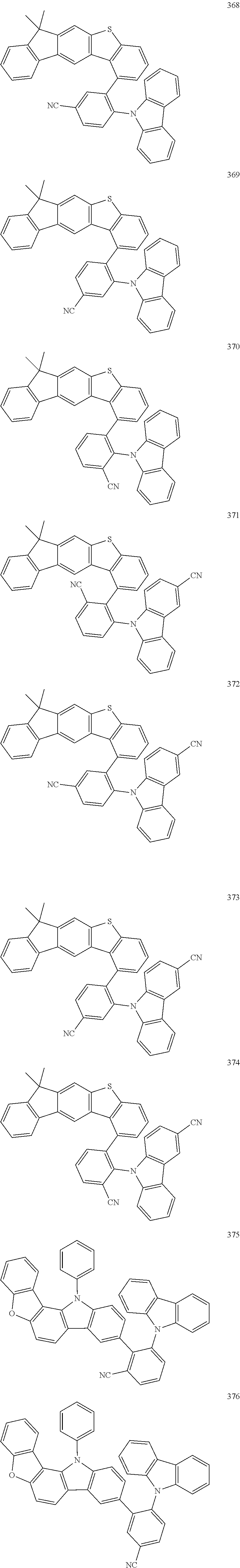

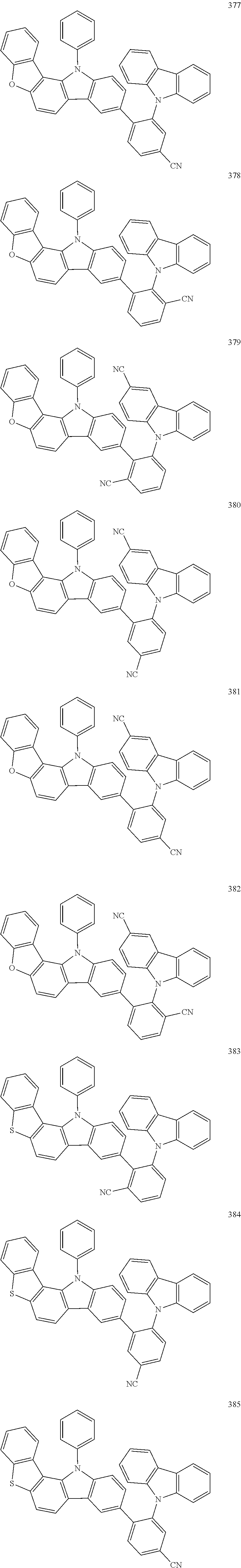

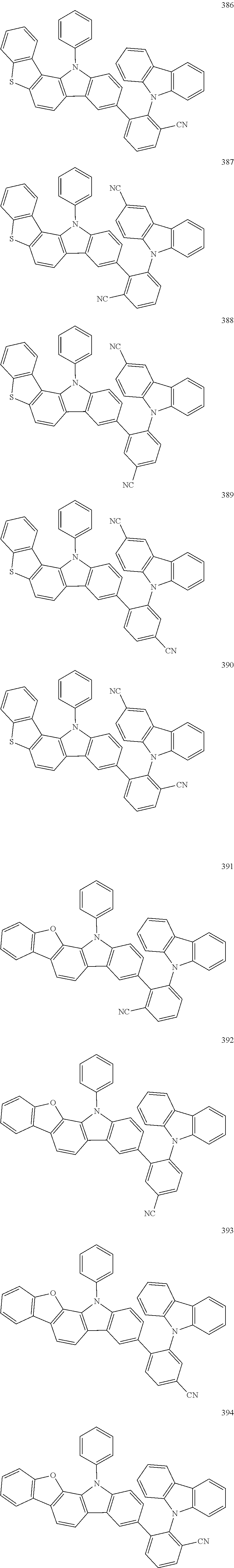

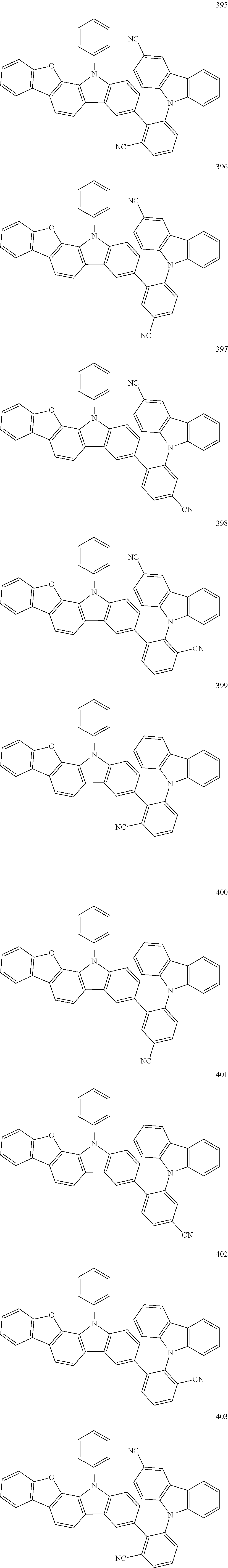

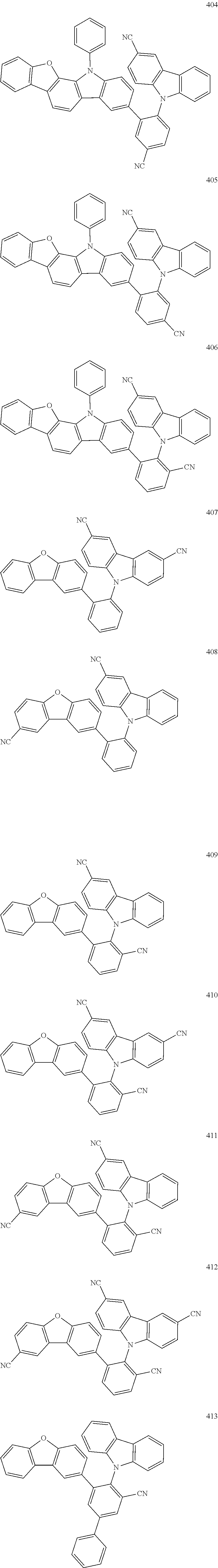

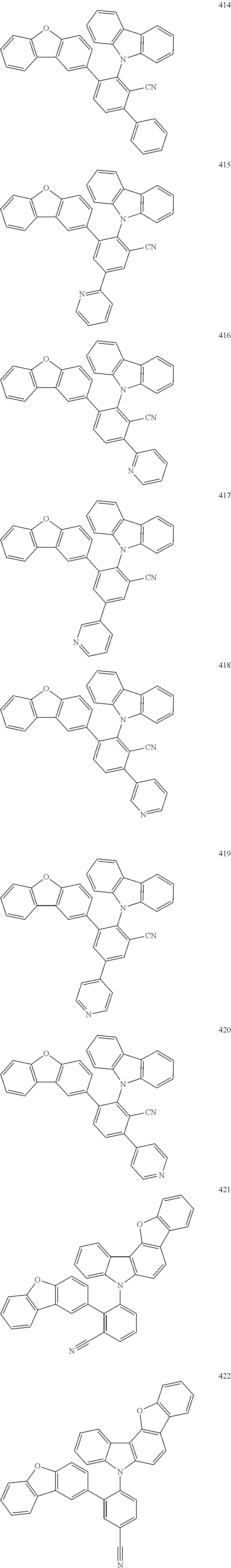

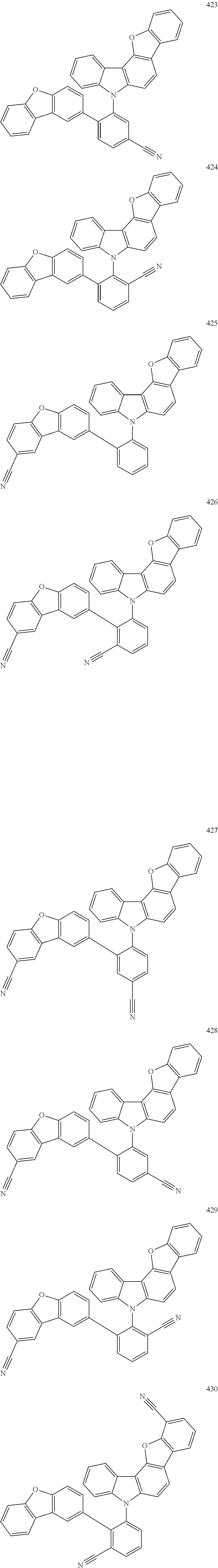

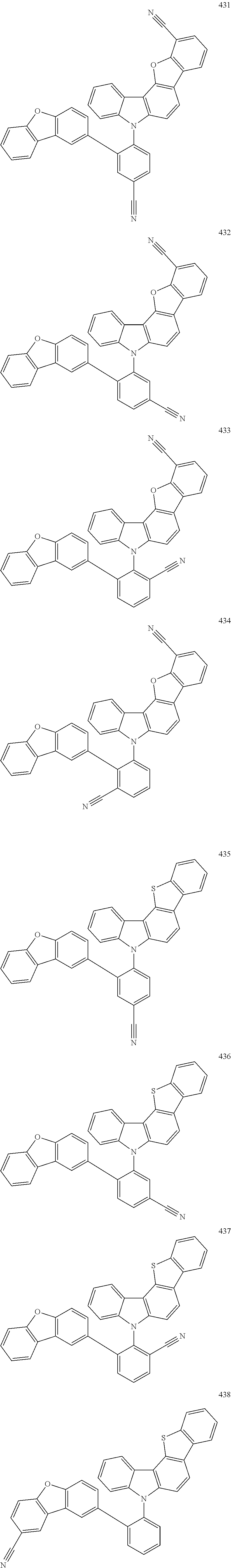

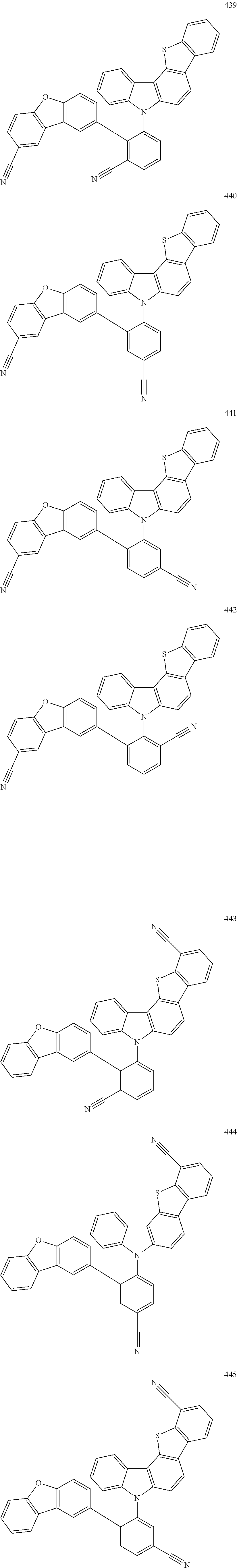

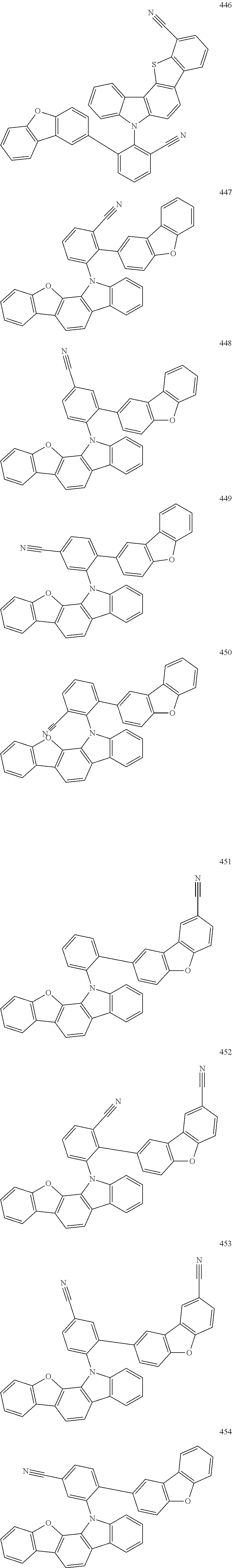

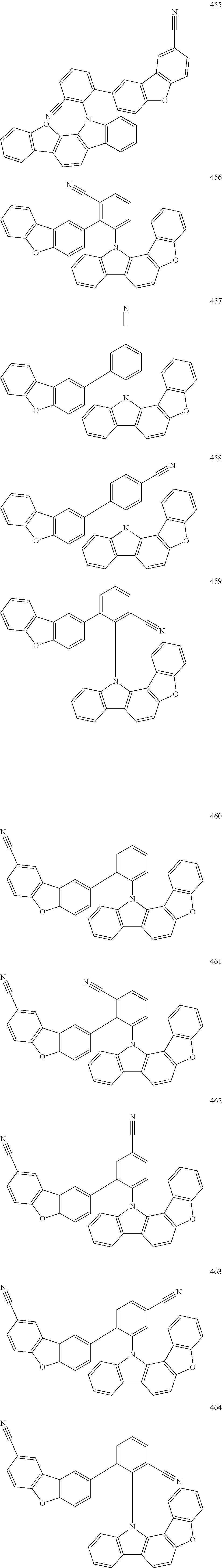

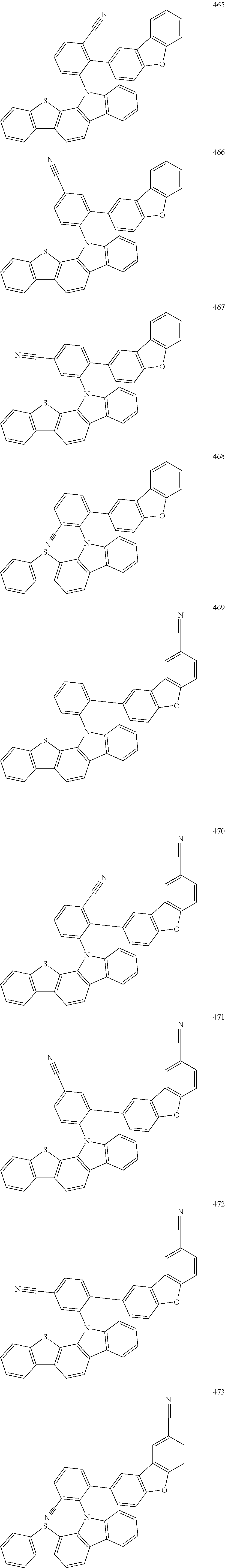

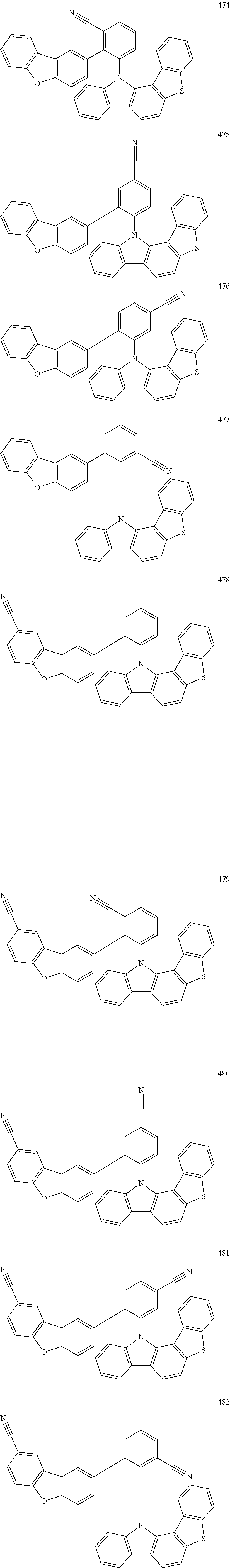

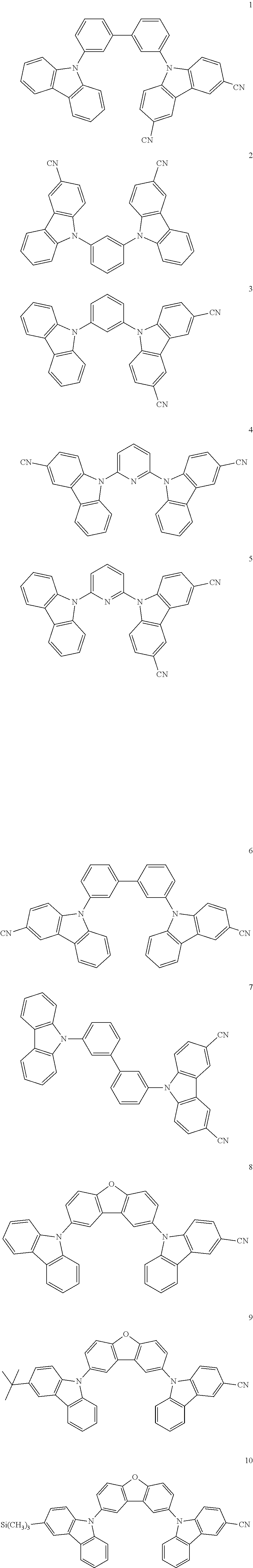

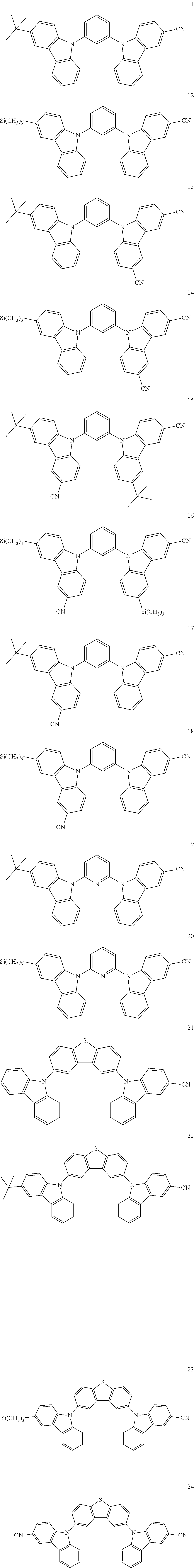

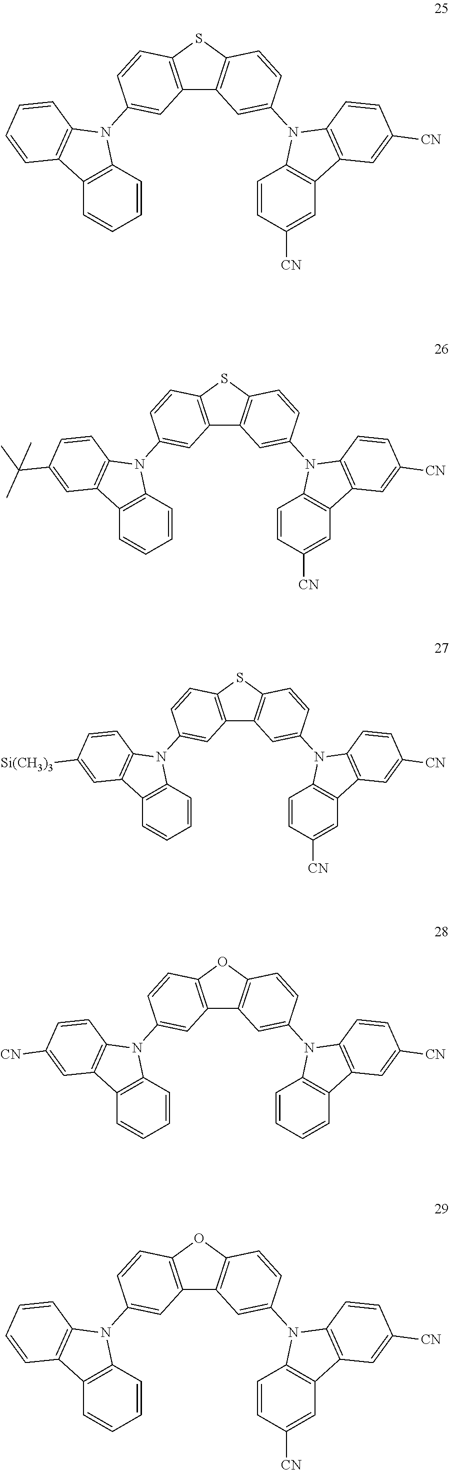

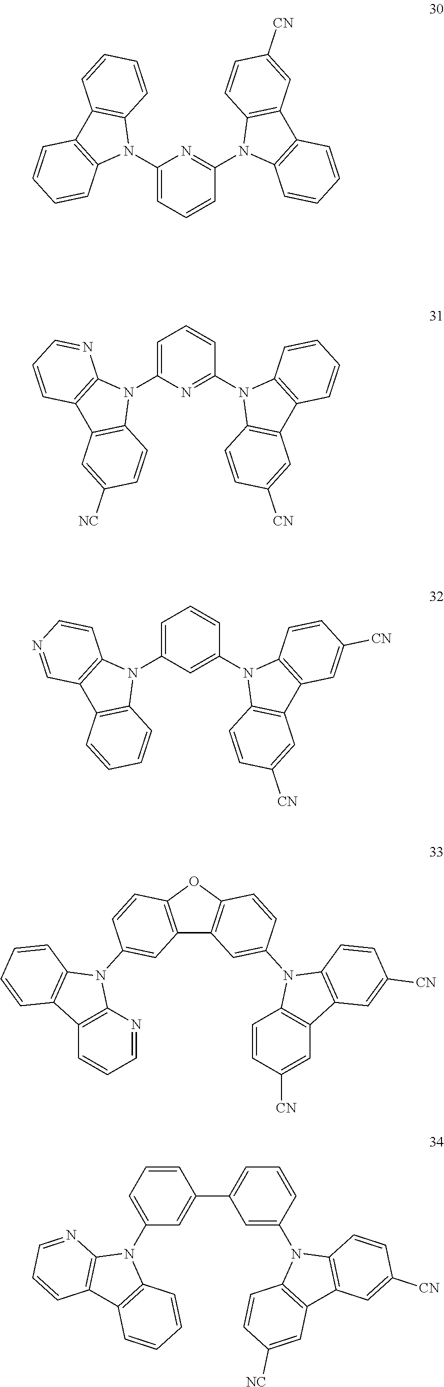 [SMILES: N#Cc1ccc2c(c1)c1ccccc1n2-c1cccc(-n2c3ccccc3c3ccccc32)n1 ; N#Cc1ccc2c(c1)c1ccccc1n2-c1cccc(-n2c3ccc(C#N)cc3c3cccnc32)n1 ; N#Cc1ccc2c(c1)c1cc(C#N)ccc1n2-c1cccc(-n2c3ccccc3c3cnccc32)c1 ; N#Cc1ccc2c(c1)c1cc(C#N)ccc1n2-c1ccc2oc3ccc(-n4c5ccccc5c5cccnc54)cc3c2c1 ; N#Cc1ccc2c(c1)c1cc(C#N)ccc1n2-c1cccc(-c2cccc(-n3c4ccccc4c4cccnc43)c2)c1]

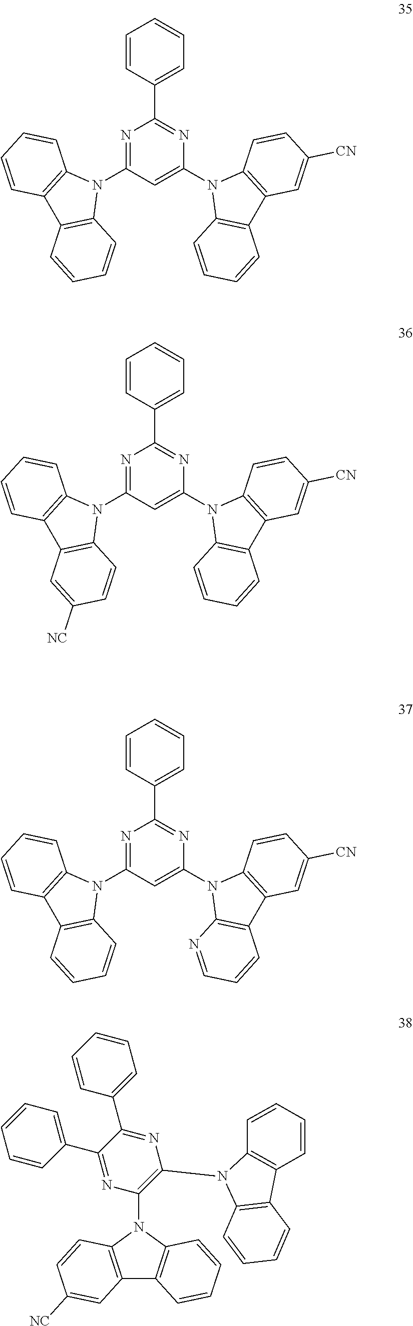 [SMILES: N#Cc1ccc2c(c1)c1ccccc1n2-c1cc(-n2c3ccccc3c3ccccc32)nc(-c2ccccc2)n1 ; N#Cc1ccc2c(c1)c1ccccc1n2-c1cc(-n2c3ccccc3c3cc(C#N)ccc32)nc(-c2ccccc2)n1 ; N#Cc1ccc2c(c1)c1cccnc1n2-c1cc(-n2c3ccccc3c3ccccc32)nc(-c2ccccc2)n1 ; N#Cc1ccc2c(c1)c1ccccc1n2-c1nc(-c2ccccc2)c(-c2ccccc2)nc1-n1c2ccccc2c2ccccc21]

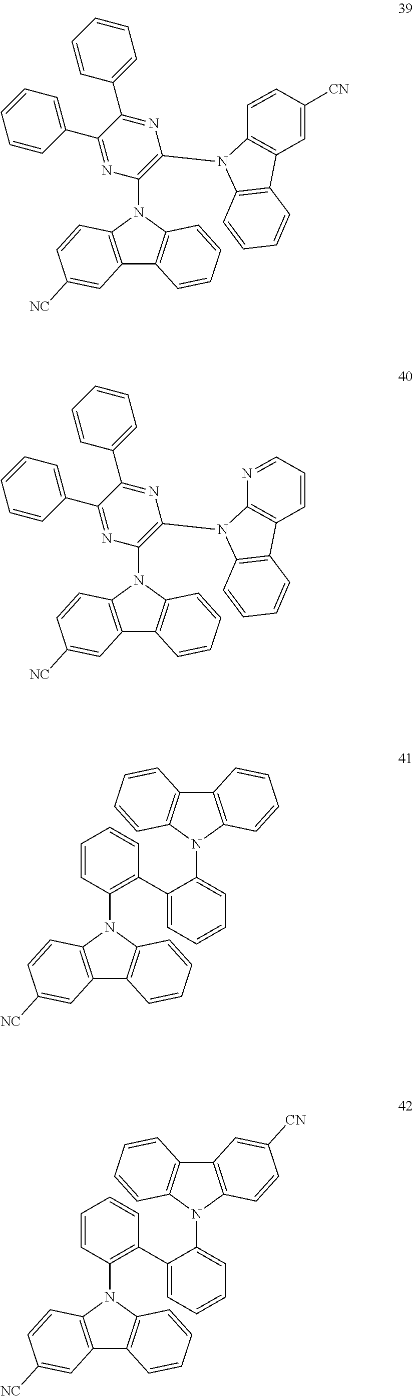 [SMILES: N#Cc1ccc2c(c1)c1ccccc1n2-c1nc(-c2ccccc2)c(-c2ccccc2)nc1-n1c2ccccc2c2cc(C#N)ccc21 ; N#Cc1ccc2c(c1)c1ccccc1n2-c1nc(-c2ccccc2)c(-c2ccccc2)nc1-n1c2ccccc2c2cccnc21 ; N#Cc1ccc2c(c1)c1ccccc1n2-c1ccccc1-c1ccccc1-n1c2ccccc2c2ccccc21 ; N#Cc1ccc2c(c1)c1ccccc1n2-c1ccccc1-c1ccccc1-n1c2ccccc2c2cc(C#N)ccc21]

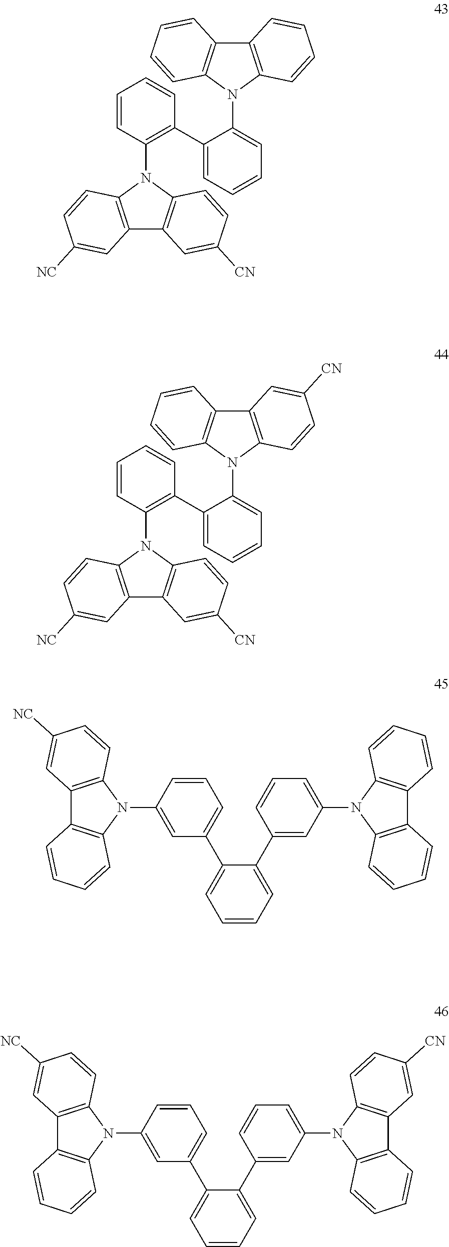 [SMILES: N#Cc1ccc2c(c1)c1cc(C#N)ccc1n2-c1ccccc1-c1ccccc1-n1c2ccccc2c2ccccc21 ; N#Cc1ccc2c(c1)c1ccccc1n2-c1ccccc1-c1ccccc1-n1c2ccc(C#N)cc2c2cc(C#N)ccc21 ; N#Cc1ccc2c(c1)c1ccccc1n2-c1cccc(-c2ccccc2-c2cccc(-n3c4ccccc4c4ccccc43)c2)c1 ; N#Cc1ccc2c(c1)c1ccccc1n2-c1cccc(-c2ccccc2-c2cccc(-n3c4ccccc4c4cc(C#N)ccc43)c2)c1]

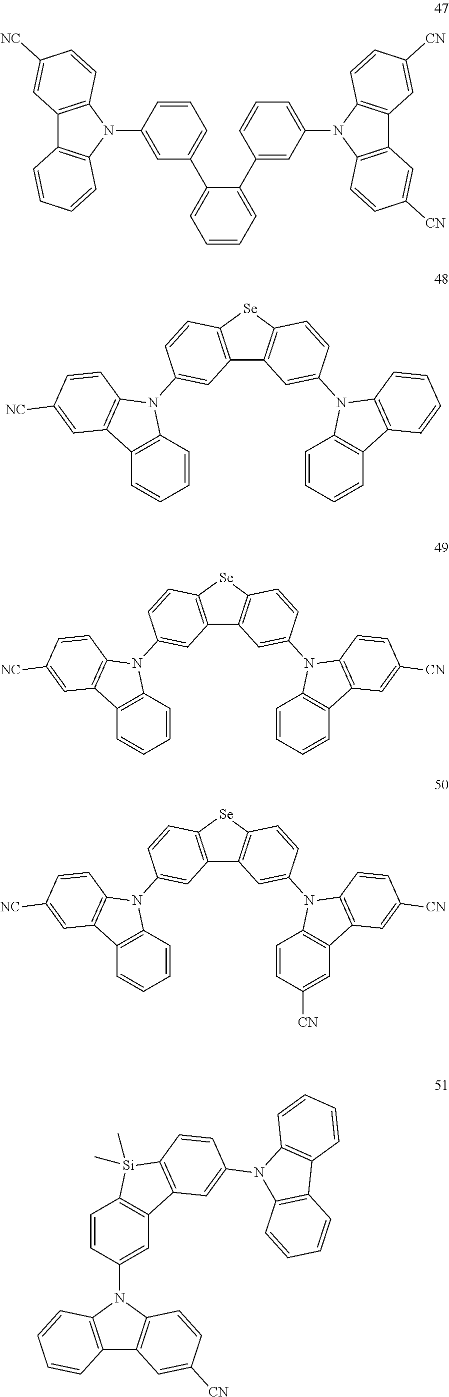 [SMILES: N#Cc1ccc2c(c1)c1ccccc1n2-c1cccc(-c2ccccc2-c2cccc(-n3c4ccc(C#N)cc4c4cc(C#N)ccc43)c2)c1 ; N#Cc1ccc2c(c1)c1ccccc1n2-c1ccc2[se]c3ccc(-n4c5ccccc5c5ccccc54)cc3c2c1 ; N#Cc1ccc2c(c1)c1ccccc1n2-c1ccc2[se]c3ccc(-n4c5ccccc5c5cc(C#N)ccc54)cc3c2c1 ; N#Cc1ccc2c(c1)c1ccccc1n2-c1ccc2[se]c3ccc(-n4c5ccc(C#N)cc5c5cc(C#N)ccc54)cc3c2c1 ; C[Si]1(C)c2ccc(-n3c4ccccc4c4ccccc43)cc2-c2cc(-n3c4ccccc4c4cc(C#N)ccc43)ccc21]

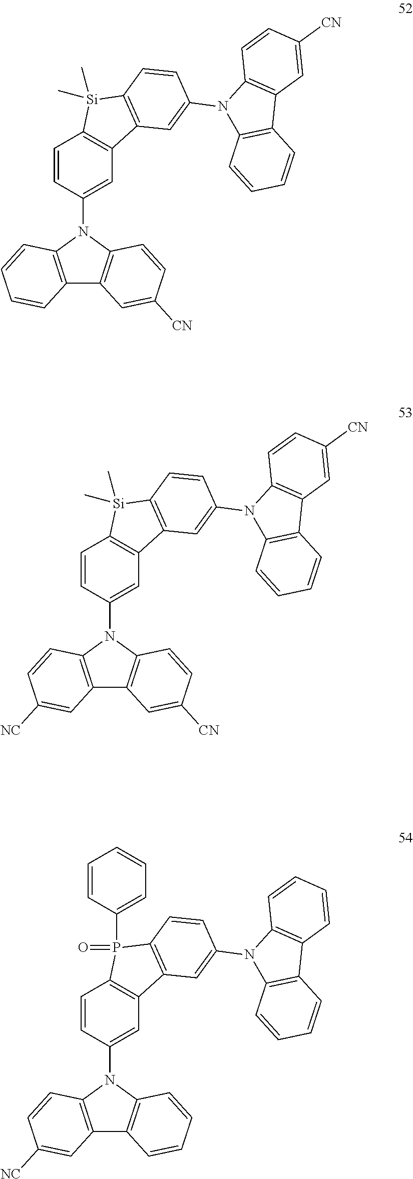 [SMILES: C[Si]1(C)c2ccc(-n3c4ccccc4c4cc(C#N)ccc43)cc2-c2cc(-n3c4ccccc4c4cc(C#N)ccc43)ccc21 ; C[Si]1(C)c2ccc(-n3c4ccccc4c4cc(C#N)ccc43)cc2-c2cc(-n3c4ccc(C#N)cc4c4cc(C#N)ccc43)ccc21 ; N#Cc1ccc2c(c1)c1ccccc1n2-c1ccc2c(c1)-c1cc(-n3c4ccccc4c4ccccc43)ccc1P2(=O)c1ccccc1]

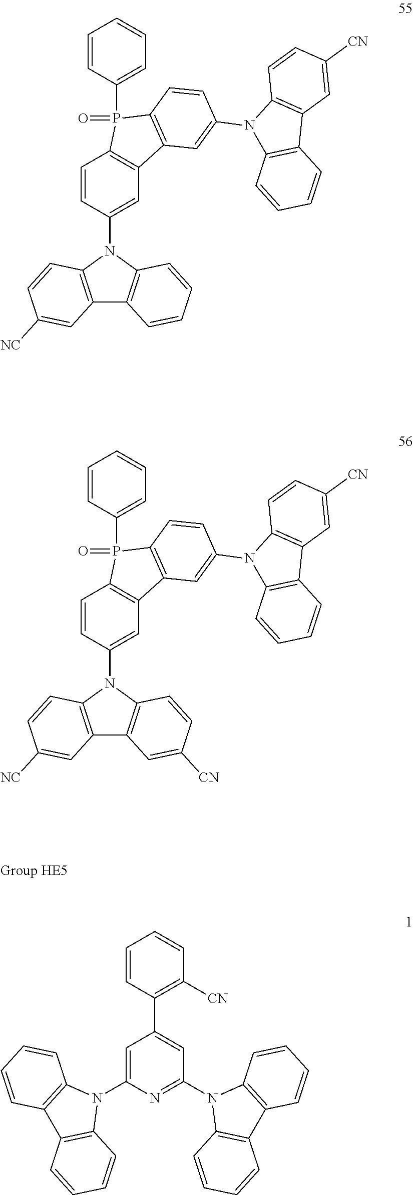 [SMILES: N#Cc1ccc2c(c1)c1ccccc1n2-c1ccc2c(c1)-c1cc(-n3c4ccccc4c4cc(C#N)ccc43)ccc1P2(=O)c1ccccc1 ; N#Cc1ccc2c(c1)c1ccccc1n2-c1ccc2c(c1)-c1cc(-n3c4ccc(C#N)cc4c4cc(C#N)ccc43)ccc1P2(=O)c1ccccc1 ; N#Cc1ccccc1-c1cc(-n2c3ccccc3c3ccccc32)nc(-n2c3ccccc3c3ccccc32)c1]

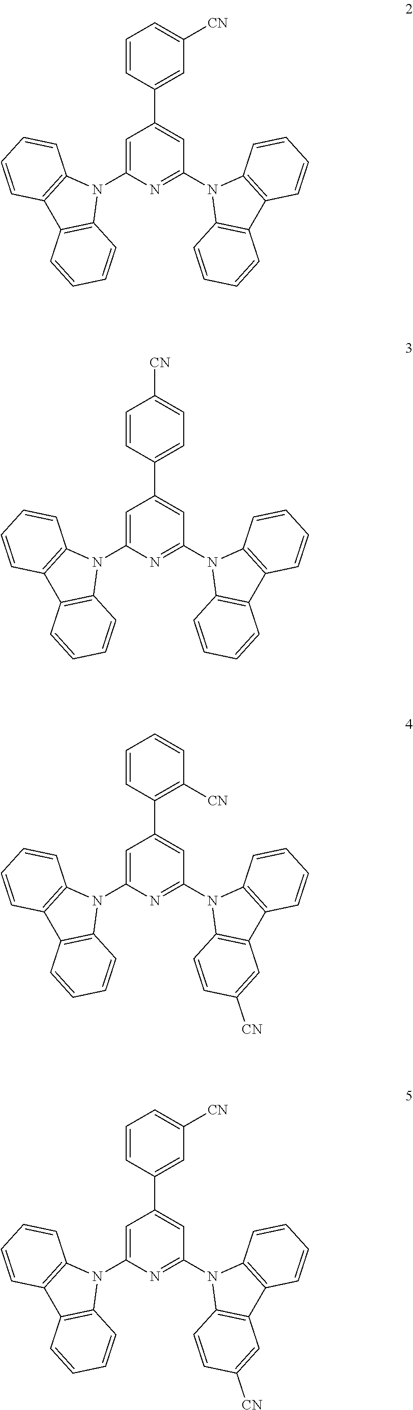 [SMILES: N#Cc1cccc(-c2cc(-n3c4ccccc4c4ccccc43)nc(-n3c4ccccc4c4ccccc43)c2)c1 ; N#Cc1ccc(-c2cc(-n3c4ccccc4c4ccccc43)nc(-n3c4ccccc4c4ccccc43)c2)cc1 ; N#Cc1ccc2c(c1)c1ccccc1n2-c1cc(-c2ccccc2C#N)cc(-n2c3ccccc3c3ccccc32)n1 ; N#Cc1cccc(-c2cc(-n3c4ccccc4c4ccccc43)nc(-n3c4ccccc4c4cc(C#N)ccc43)c2)c1]

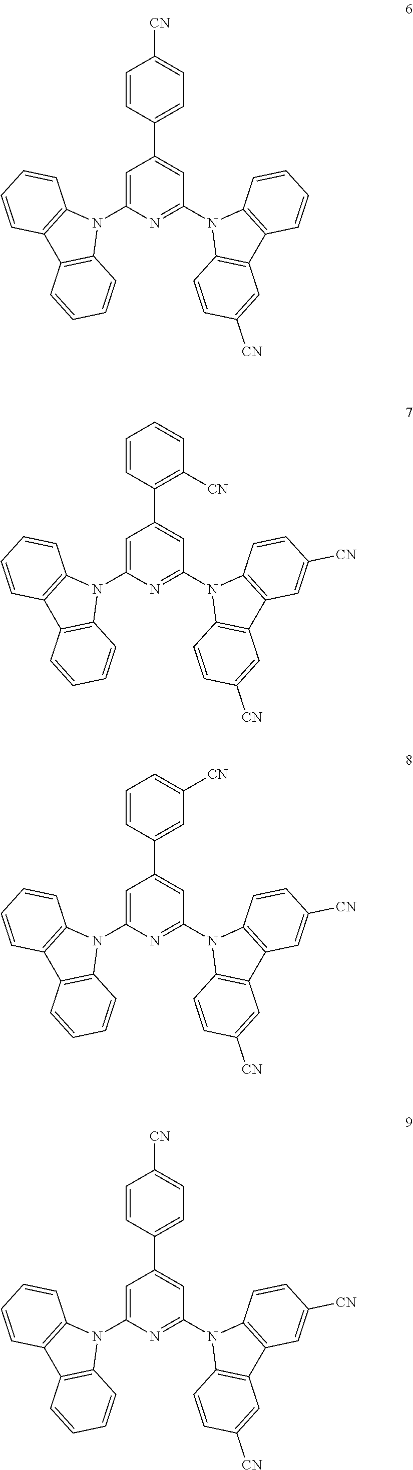 [SMILES: N#Cc1ccc(-c2cc(-n3c4ccccc4c4ccccc43)nc(-n3c4ccccc4c4cc(C#N)ccc43)c2)cc1 ; N#Cc1ccc2c(c1)c1cc(C#N)ccc1n2-c1cc(-c2ccccc2C#N)cc(-n2c3ccccc3c3ccccc32)n1 ; N#Cc1cccc(-c2cc(-n3c4ccccc4c4ccccc43)nc(-n3c4ccc(C#N)cc4c4cc(C#N)ccc43)c2)c1 ; N#Cc1ccc(-c2cc(-n3c4ccccc4c4ccccc43)nc(-n3c4ccc(C#N)cc4c4cc(C#N)ccc43)c2)cc1]

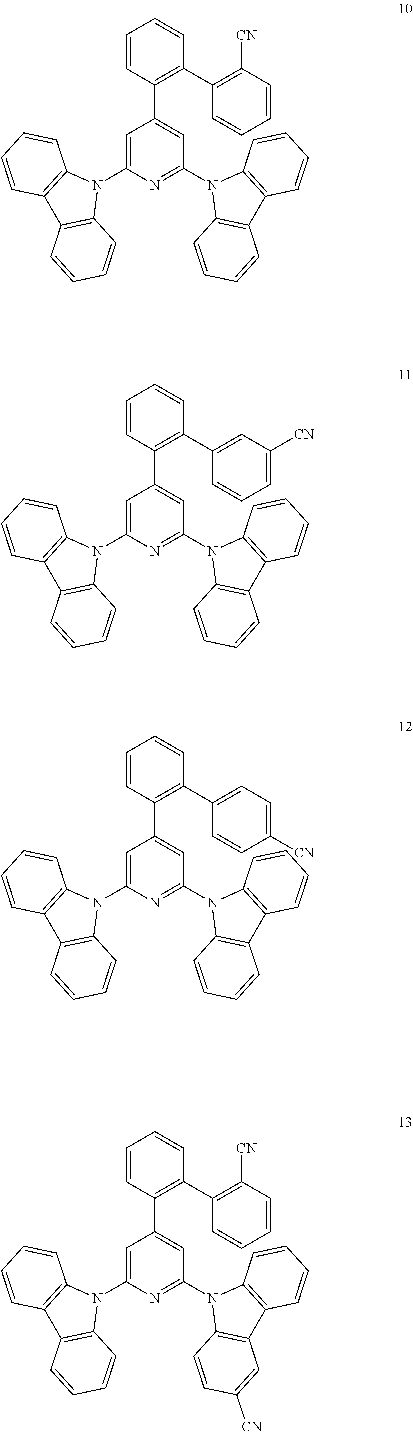 [SMILES: N#Cc1ccccc1-c1ccccc1-c1cc(-n2c3ccccc3c3ccccc32)nc(-n2c3ccccc3c3ccccc32)c1 ; N#Cc1cccc(-c2ccccc2-c2cc(-n3c4ccccc4c4ccccc43)nc(-n3c4ccccc4c4ccccc43)c2)c1 ; N#Cc1ccc(-c2ccccc2-c2cc(-n3c4ccccc4c4ccccc43)nc(-n3c4ccccc4c4ccccc43)c2)cc1 ; N#Cc1ccc2c(c1)c1ccccc1n2-c1cc(-c2ccccc2-c2ccccc2C#N)cc(-n2c3ccccc3c3ccccc32)n1]

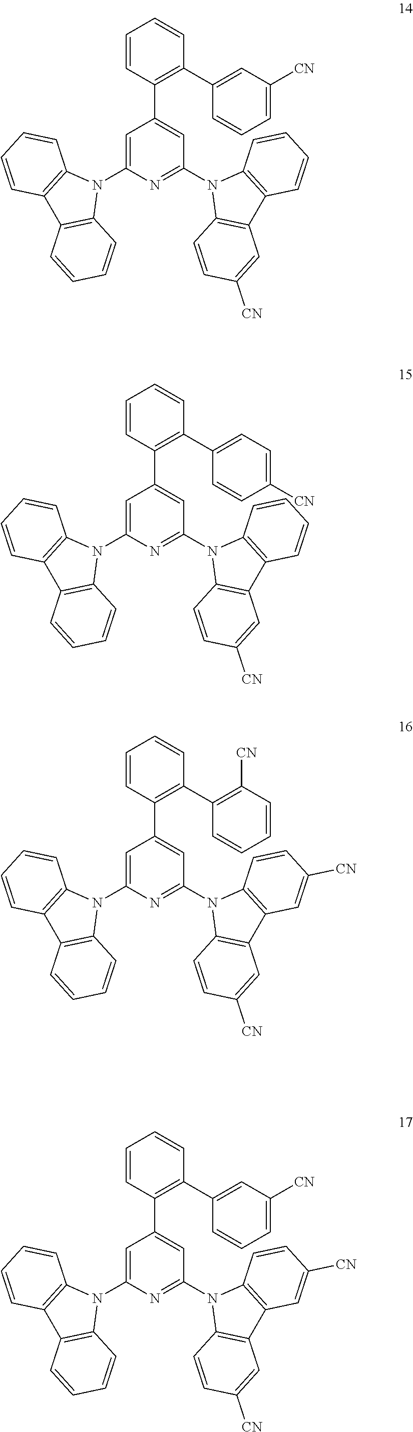 [SMILES: N#Cc1cccc(-c2ccccc2-c2cc(-n3c4ccccc4c4ccccc43)nc(-n3c4ccccc4c4cc(C#N)ccc43)c2)c1 ; N#Cc1ccc(-c2ccccc2-c2cc(-n3c4ccccc4c4ccccc43)nc(-n3c4ccccc4c4cc(C#N)ccc43)c2)cc1 ; N#Cc1ccc2c(c1)c1cc(C#N)ccc1n2-c1cc(-c2ccccc2-c2ccccc2C#N)cc(-n2c3ccccc3c3ccccc32)n1 ; N#Cc1cccc(-c2ccccc2-c2cc(-n3c4ccccc4c4ccccc43)nc(-n3c4ccc(C#N)cc4c4cc(C#N)ccc43)c2)c1]

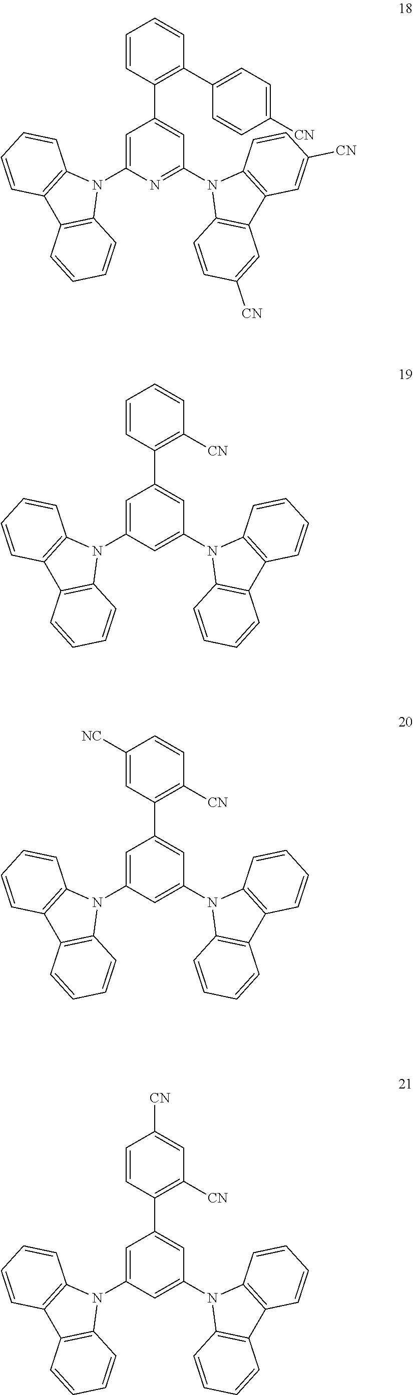 [SMILES: N#Cc1ccc(-c2ccccc2-c2cc(-n3c4ccccc4c4ccccc43)nc(-n3c4ccc(C#N)cc4c4cc(C#N)ccc43)c2)cc1 ; N#Cc1ccccc1-c1cc(-n2c3ccccc3c3ccccc32)cc(-n2c3ccccc3c3ccccc32)c1 ; N#Cc1ccc(C#N)c(-c2cc(-n3c4ccccc4c4ccccc43)cc(-n3c4ccccc4c4ccccc43)c2)c1 ; N#Cc1ccc(-c2cc(-n3c4ccccc4c4ccccc43)cc(-n3c4ccccc4c4ccccc43)c2)c(C#N)c1]

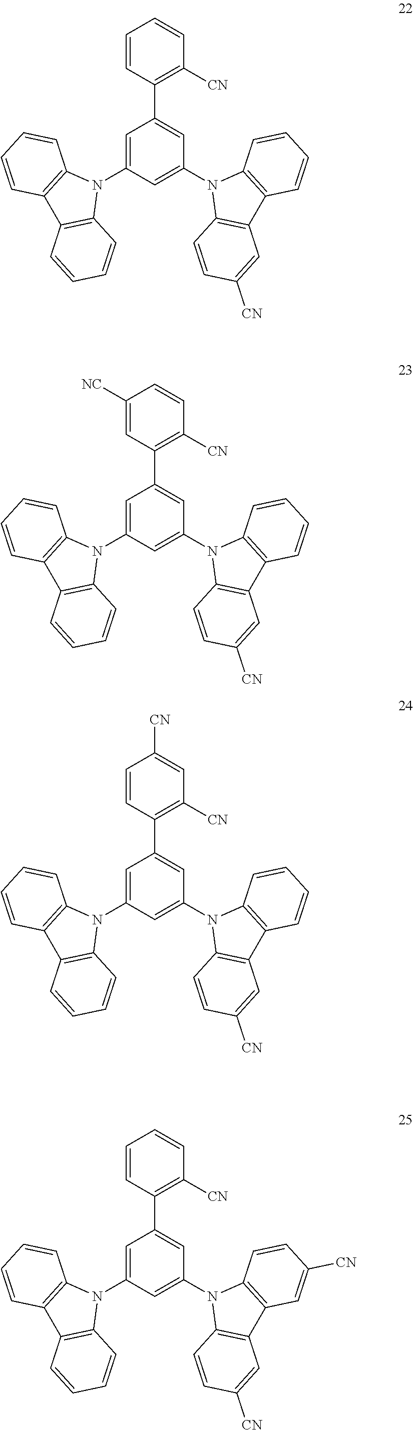 [SMILES: N#Cc1ccc2c(c1)c1ccccc1n2-c1cc(-c2ccccc2C#N)cc(-n2c3ccccc3c3ccccc32)c1 ; N#Cc1ccc(C#N)c(-c2cc(-n3c4ccccc4c4ccccc43)cc(-n3c4ccccc4c4cc(C#N)ccc43)c2)c1 ; N#Cc1ccc(-c2cc(-n3c4ccccc4c4ccccc43)cc(-n3c4ccccc4c4cc(C#N)ccc43)c2)c(C#N)c1 ; N#Cc1ccc2c(c1)c1cc(C#N)ccc1n2-c1cc(-c2ccccc2C#N)cc(-n2c3ccccc3c3ccccc32)c1]

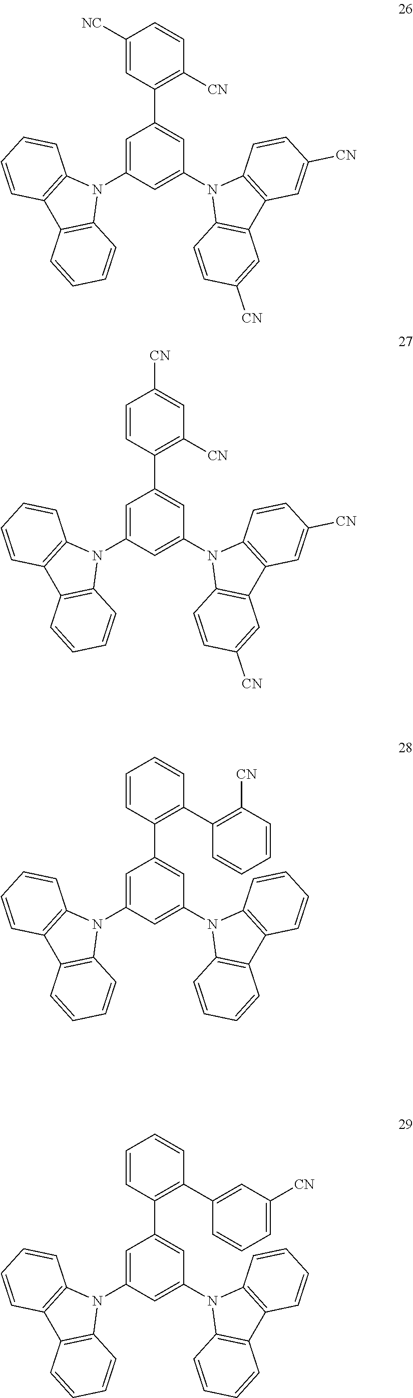 [SMILES: N#Cc1ccc(C#N)c(-c2cc(-n3c4ccccc4c4ccccc43)cc(-n3c4ccc(C#N)cc4c4cc(C#N)ccc43)c2)c1 ; N#Cc1ccc(-c2cc(-n3c4ccccc4c4ccccc43)cc(-n3c4ccc(C#N)cc4c4cc(C#N)ccc43)c2)c(C#N)c1 ; N#Cc1ccccc1-c1ccccc1-c1cc(-n2c3ccccc3c3ccccc32)cc(-n2c3ccccc3c3ccccc32)c1 ; N#Cc1cccc(-c2ccccc2-c2cc(-n3c4ccccc4c4ccccc43)cc(-n3c4ccccc4c4ccccc43)c2)c1]

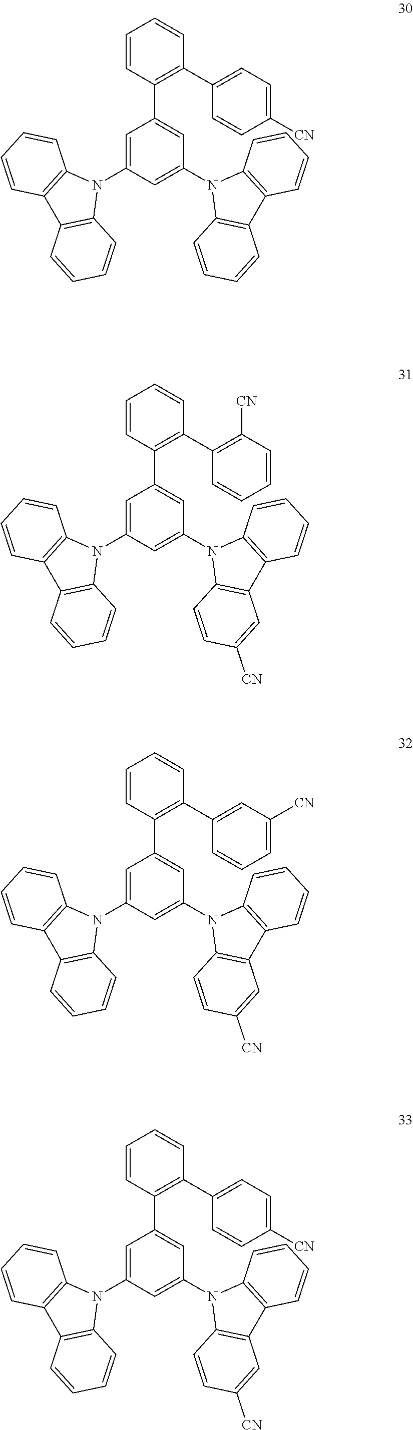 [SMILES: N#Cc1ccc(-c2ccccc2-c2cc(-n3c4ccccc4c4ccccc43)cc(-n3c4ccccc4c4ccccc43)c2)cc1 ; N#Cc1ccc2c(c1)c1ccccc1n2-c1cc(-c2ccccc2-c2ccccc2C#N)cc(-n2c3ccccc3c3ccccc32)c1 ; N#Cc1cccc(-c2ccccc2-c2cc(-n3c4ccccc4c4ccccc43)cc(-n3c4ccccc4c4cc(C#N)ccc43)c2)c1 ; N#Cc1ccc(-c2ccccc2-c2cc(-n3c4ccccc4c4ccccc43)cc(-n3c4ccccc4c4cc(C#N)ccc43)c2)cc1]

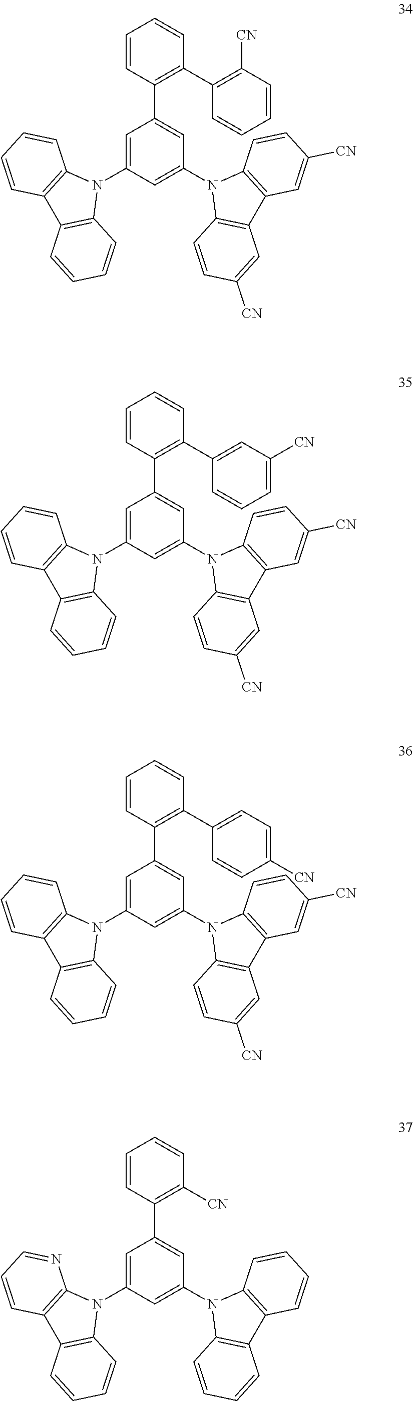 [SMILES: N#Cc1ccc2c(c1)c1cc(C#N)ccc1n2-c1cc(-c2ccccc2-c2ccccc2C#N)cc(-n2c3ccccc3c3ccccc32)c1 ; N#Cc1cccc(-c2ccccc2-c2cc(-n3c4ccccc4c4ccccc43)cc(-n3c4ccc(C#N)cc4c4cc(C#N)ccc43)c2)c1 ; N#Cc1ccc(-c2ccccc2-c2cc(-n3c4ccccc4c4ccccc43)cc(-n3c4ccc(C#N)cc4c4cc(C#N)ccc43)c2)cc1 ; N#Cc1ccccc1-c1cc(-n2c3ccccc3c3ccccc32)cc(-n2c3ccccc3c3cccnc32)c1]

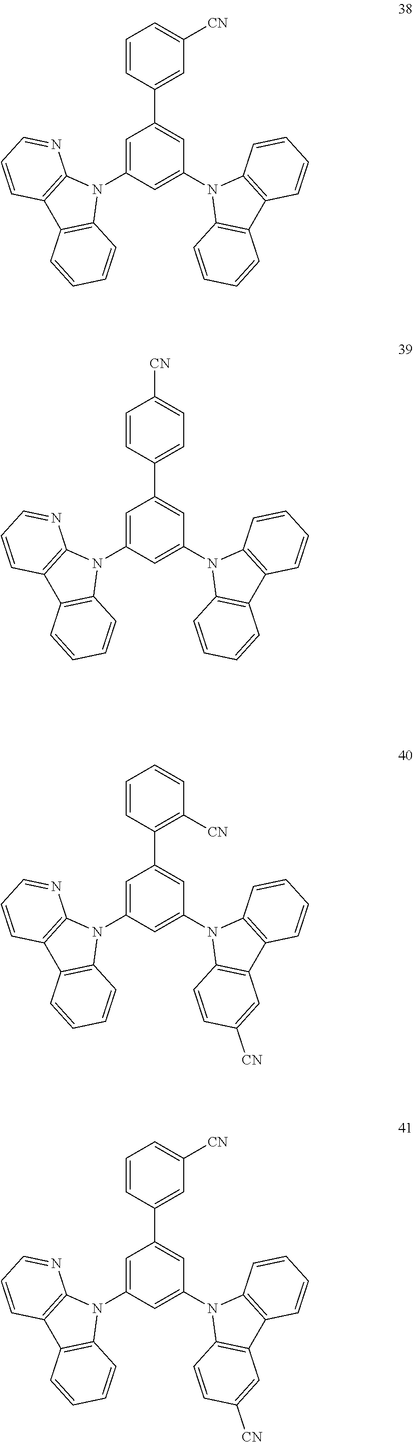 [SMILES: N#Cc1cccc(-c2cc(-n3c4ccccc4c4ccccc43)cc(-n3c4ccccc4c4cccnc43)c2)c1 ; N#Cc1ccc(-c2cc(-n3c4ccccc4c4ccccc43)cc(-n3c4ccccc4c4cccnc43)c2)cc1 ; N#Cc1ccc2c(c1)c1ccccc1n2-c1cc(-c2ccccc2C#N)cc(-n2c3ccccc3c3cccnc32)c1 ; N#Cc1cccc(-c2cc(-n3c4ccccc4c4cc(C#N)ccc43)cc(-n3c4ccccc4c4cccnc43)c2)c1]

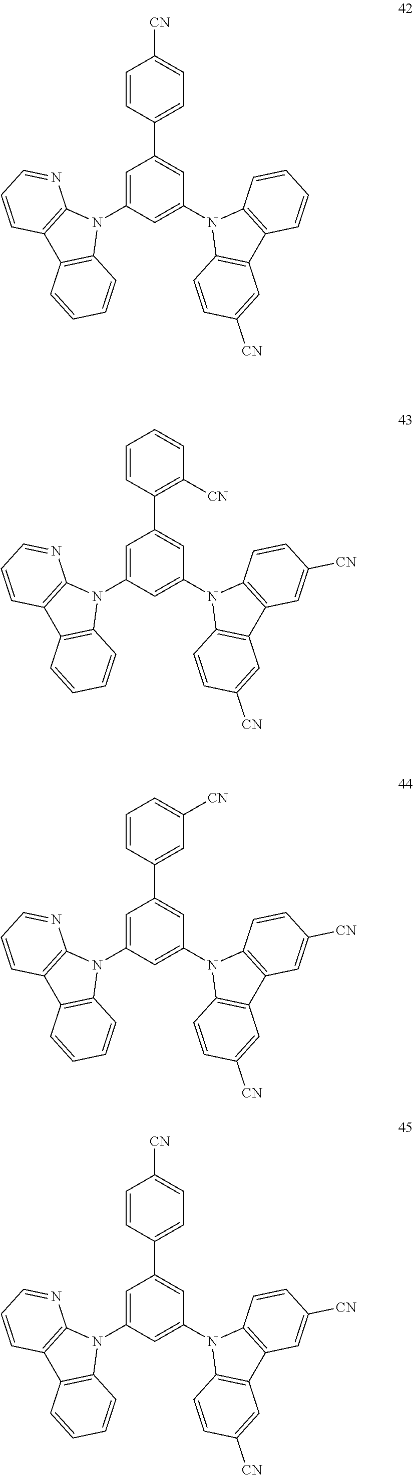 [SMILES: N#Cc1ccc(-c2cc(-n3c4ccccc4c4cc(C#N)ccc43)cc(-n3c4ccccc4c4cccnc43)c2)cc1 ; N#Cc1ccc2c(c1)c1cc(C#N)ccc1n2-c1cc(-c2ccccc2C#N)cc(-n2c3ccccc3c3cccnc32)c1 ; N#Cc1cccc(-c2cc(-n3c4ccc(C#N)cc4c4cc(C#N)ccc43)cc(-n3c4ccccc4c4cccnc43)c2)c1 ; N#Cc1ccc(-c2cc(-n3c4ccc(C#N)cc4c4cc(C#N)ccc43)cc(-n3c4ccccc4c4cccnc43)c2)cc1]

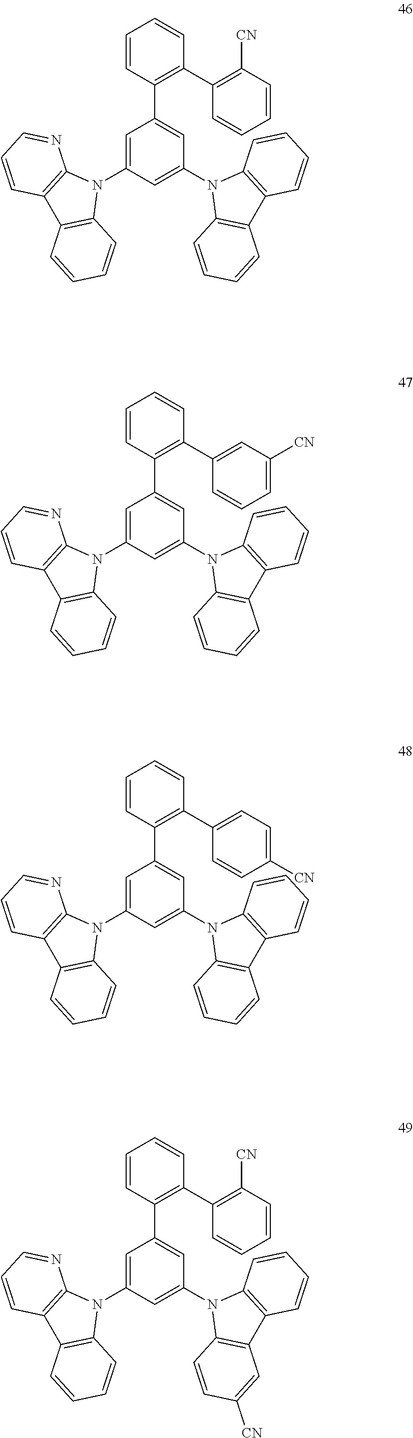 [SMILES: N#Cc1ccccc1-c1ccccc1-c1cc(-n2c3ccccc3c3ccccc32)cc(-n2c3ccccc3c3cccnc32)c1 ; N#Cc1cccc(-c2ccccc2-c2cc(-n3c4ccccc4c4ccccc43)cc(-n3c4ccccc4c4cccnc43)c2)c1 ; N#Cc1ccc(-c2ccccc2-c2cc(-n3c4ccccc4c4ccccc43)cc(-n3c4ccccc4c4cccnc43)c2)cc1 ; N#Cc1ccc2c(c1)c1ccccc1n2-c1cc(-c2ccccc2-c2ccccc2C#N)cc(-n2c3ccccc3c3cccnc32)c1]

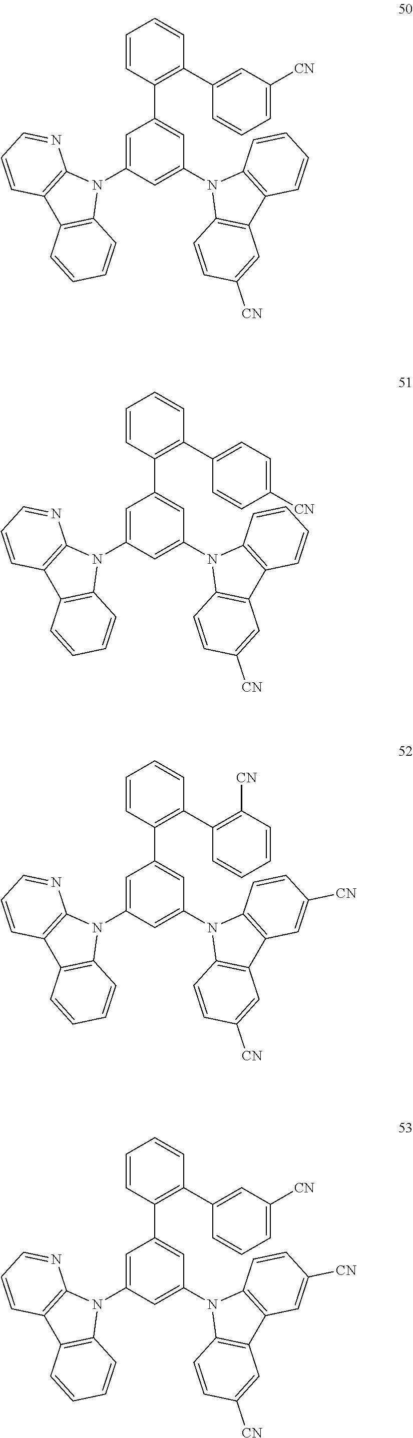 [SMILES: N#Cc1cccc(-c2ccccc2-c2cc(-n3c4ccccc4c4cc(C#N)ccc43)cc(-n3c4ccccc4c4cccnc43)c2)c1 ; N#Cc1ccc(-c2ccccc2-c2cc(-n3c4ccccc4c4cc(C#N)ccc43)cc(-n3c4ccccc4c4cccnc43)c2)cc1 ; N#Cc1ccc2c(c1)c1cc(C#N)ccc1n2-c1cc(-c2ccccc2-c2ccccc2C#N)cc(-n2c3ccccc3c3cccnc32)c1 ; N#Cc1cccc(-c2ccccc2-c2cc(-n3c4ccc(C#N)cc4c4cc(C#N)ccc43)cc(-n3c4ccccc4c4cccnc43)c2)c1]

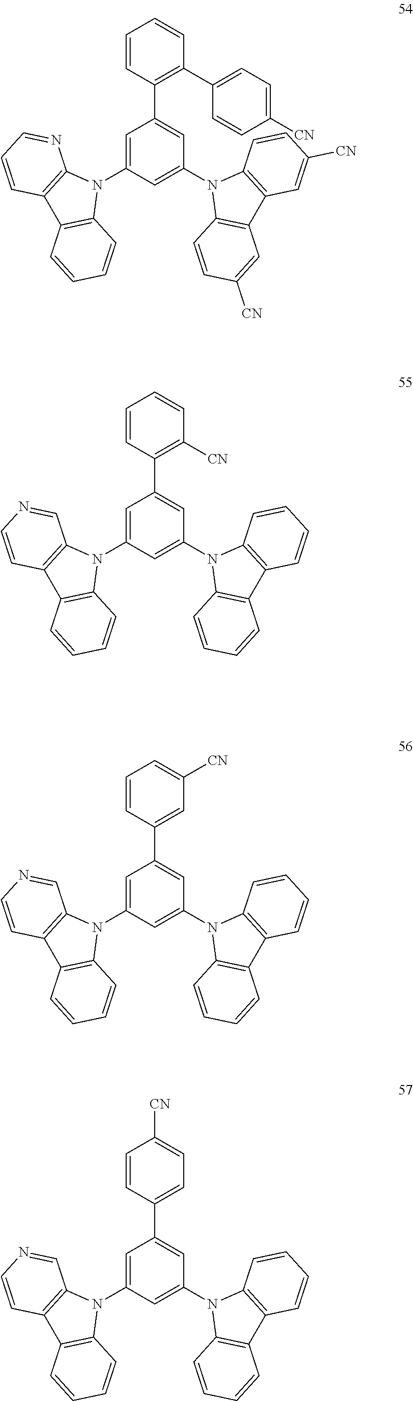 [SMILES: N#Cc1ccc(-c2ccccc2-c2cc(-n3c4ccc(C#N)cc4c4cc(C#N)ccc43)cc(-n3c4ccccc4c4cccnc43)c2)cc1 ; N#Cc1ccccc1-c1cc(-n2c3ccccc3c3ccccc32)cc(-n2c3ccccc3c3ccncc32)c1 ; N#Cc1cccc(-c2cc(-n3c4ccccc4c4ccccc43)cc(-n3c4ccccc4c4ccncc43)c2)c1 ; N#Cc1ccc(-c2cc(-n3c4ccccc4c4ccccc43)cc(-n3c4ccccc4c4ccncc43)c2)cc1]

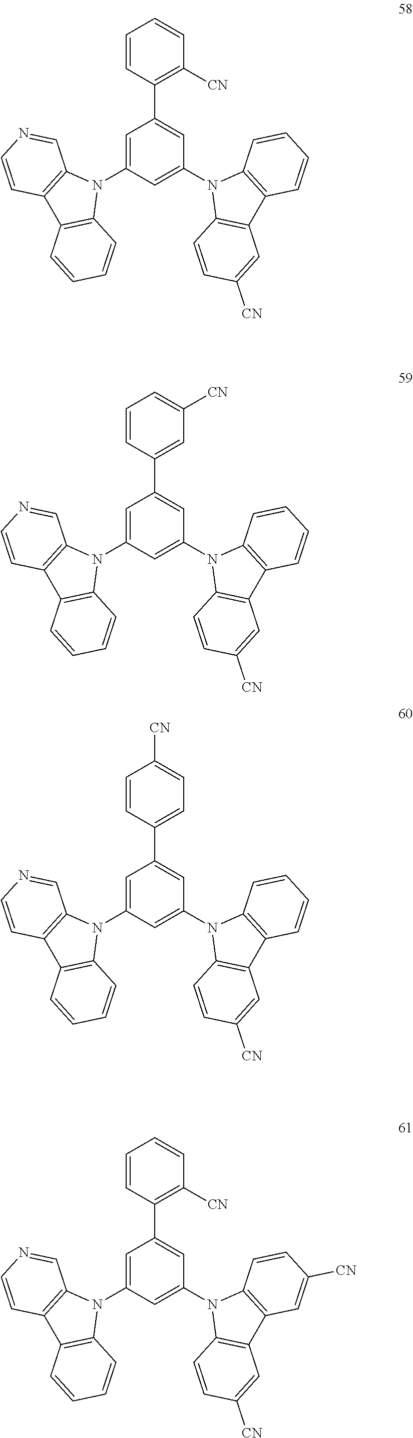 [SMILES: N#Cc1ccc2c(c1)c1ccccc1n2-c1cc(-c2ccccc2C#N)cc(-n2c3ccccc3c3ccncc32)c1 ; N#Cc1cccc(-c2cc(-n3c4ccccc4c4cc(C#N)ccc43)cc(-n3c4ccccc4c4ccncc43)c2)c1 ; N#Cc1ccc(-c2cc(-n3c4ccccc4c4cc(C#N)ccc43)cc(-n3c4ccccc4c4ccncc43)c2)cc1 ; N#Cc1ccc2c(c1)c1cc(C#N)ccc1n2-c1cc(-c2ccccc2C#N)cc(-n2c3ccccc3c3ccncc32)c1]

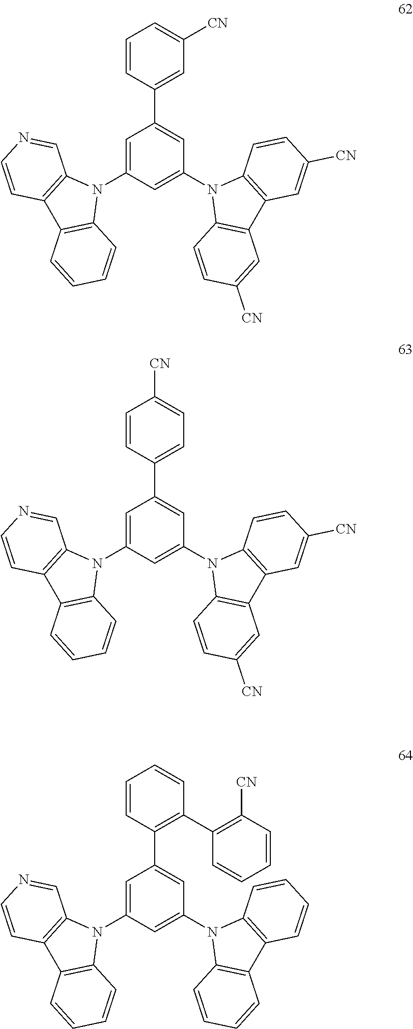 [SMILES: N#Cc1cccc(-c2cc(-n3c4ccc(C#N)cc4c4cc(C#N)ccc43)cc(-n3c4ccccc4c4ccncc43)c2)c1 ; N#Cc1ccc(-c2cc(-n3c4ccc(C#N)cc4c4cc(C#N)ccc43)cc(-n3c4ccccc4c4ccncc43)c2)cc1 ; N#Cc1ccccc1-c1ccccc1-c1cc(-n2c3ccccc3c3ccccc32)cc(-n2c3ccccc3c3ccncc32)c1]

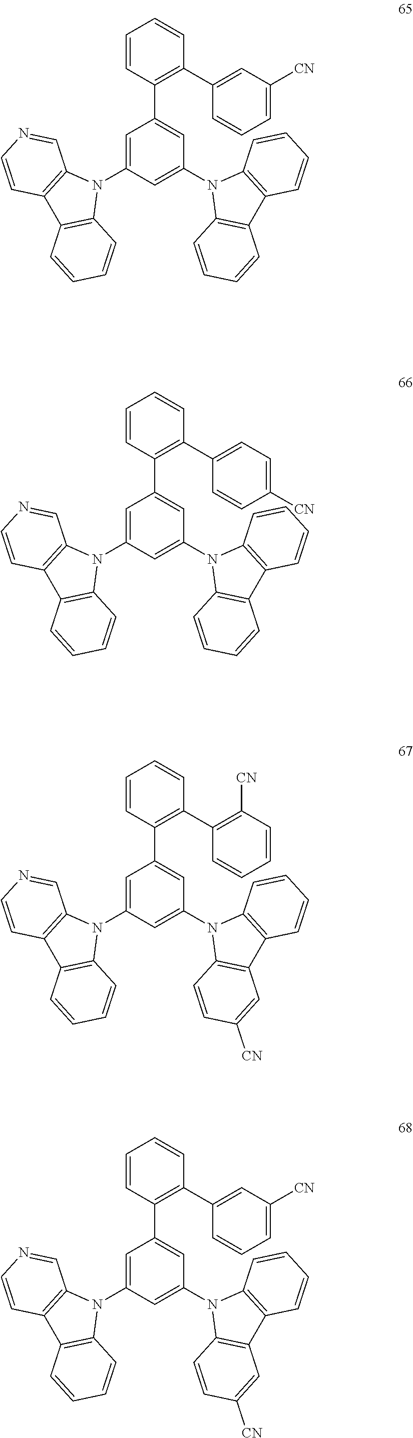 [SMILES: N#Cc1cccc(-c2ccccc2-c2cc(-n3c4ccccc4c4ccccc43)cc(-n3c4ccccc4c4ccncc43)c2)c1 ; N#Cc1ccc(-c2ccccc2-c2cc(-n3c4ccccc4c4ccccc43)cc(-n3c4ccccc4c4ccncc43)c2)cc1 ; N#Cc1ccc2c(c1)c1ccccc1n2-c1cc(-c2ccccc2-c2ccccc2C#N)cc(-n2c3ccccc3c3ccncc32)c1 ; N#Cc1cccc(-c2ccccc2-c2cc(-n3c4ccccc4c4cc(C#N)ccc43)cc(-n3c4ccccc4c4ccncc43)c2)c1]

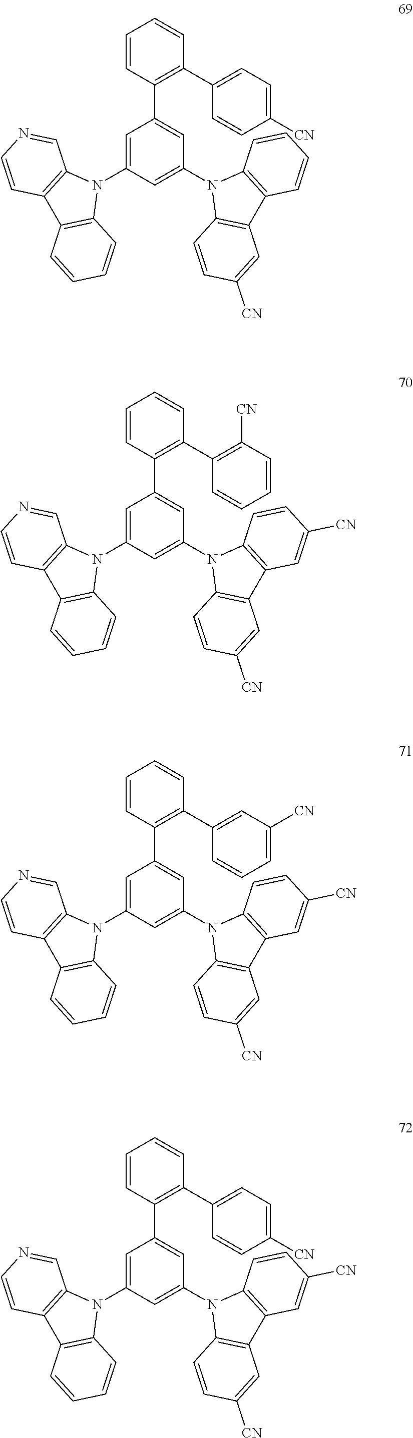 [SMILES: N#Cc1ccc(-c2ccccc2-c2cc(-n3c4ccccc4c4cc(C#N)ccc43)cc(-n3c4ccccc4c4ccncc43)c2)cc1 ; N#Cc1ccc2c(c1)c1cc(C#N)ccc1n2-c1cc(-c2ccccc2-c2ccccc2C#N)cc(-n2c3ccccc3c3ccncc32)c1 ; N#Cc1cccc(-c2ccccc2-c2cc(-n3c4ccc(C#N)cc4c4cc(C#N)ccc43)cc(-n3c4ccccc4c4ccncc43)c2)c1 ; N#Cc1ccc(-c2ccccc2-c2cc(-n3c4ccc(C#N)cc4c4cc(C#N)ccc43)cc(-n3c4ccccc4c4ccncc43)c2)cc1]

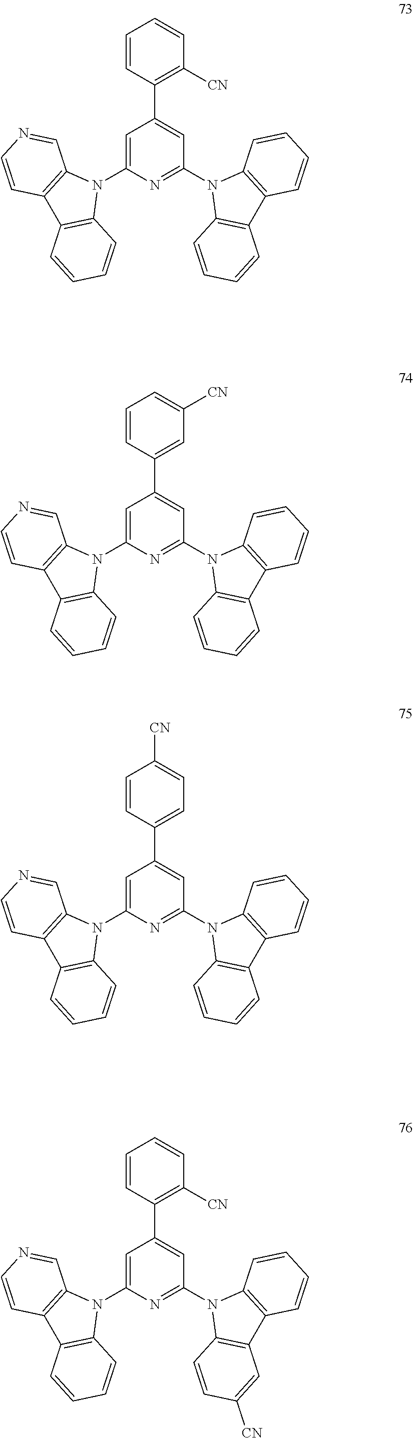 [SMILES: N#Cc1ccccc1-c1cc(-n2c3ccccc3c3ccccc32)nc(-n2c3ccccc3c3ccncc32)c1 ; N#Cc1cccc(-c2cc(-n3c4ccccc4c4ccccc43)nc(-n3c4ccccc4c4ccncc43)c2)c1 ; N#Cc1ccc(-c2cc(-n3c4ccccc4c4ccccc43)nc(-n3c4ccccc4c4ccncc43)c2)cc1 ; N#Cc1ccc2c(c1)c1ccccc1n2-c1cc(-c2ccccc2C#N)cc(-n2c3ccccc3c3ccncc32)n1]

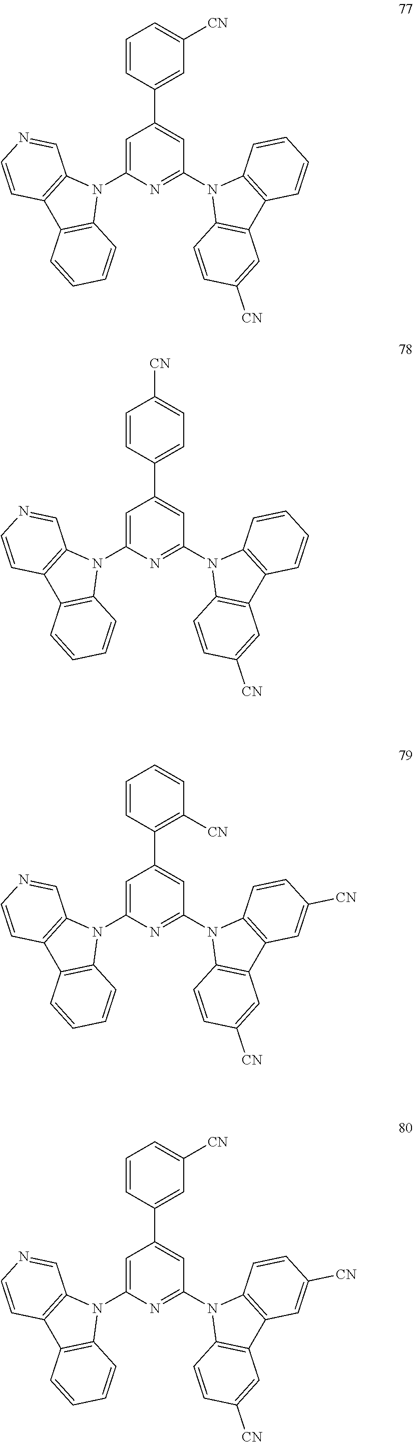 [SMILES: N#Cc1cccc(-c2cc(-n3c4ccccc4c4cc(C#N)ccc43)nc(-n3c4ccccc4c4ccncc43)c2)c1 ; N#Cc1ccc(-c2cc(-n3c4ccccc4c4cc(C#N)ccc43)nc(-n3c4ccccc4c4ccncc43)c2)cc1 ; N#Cc1ccc2c(c1)c1cc(C#N)ccc1n2-c1cc(-c2ccccc2C#N)cc(-n2c3ccccc3c3ccncc32)n1 ; N#Cc1cccc(-c2cc(-n3c4ccc(C#N)cc4c4cc(C#N)ccc43)nc(-n3c4ccccc4c4ccncc43)c2)c1]

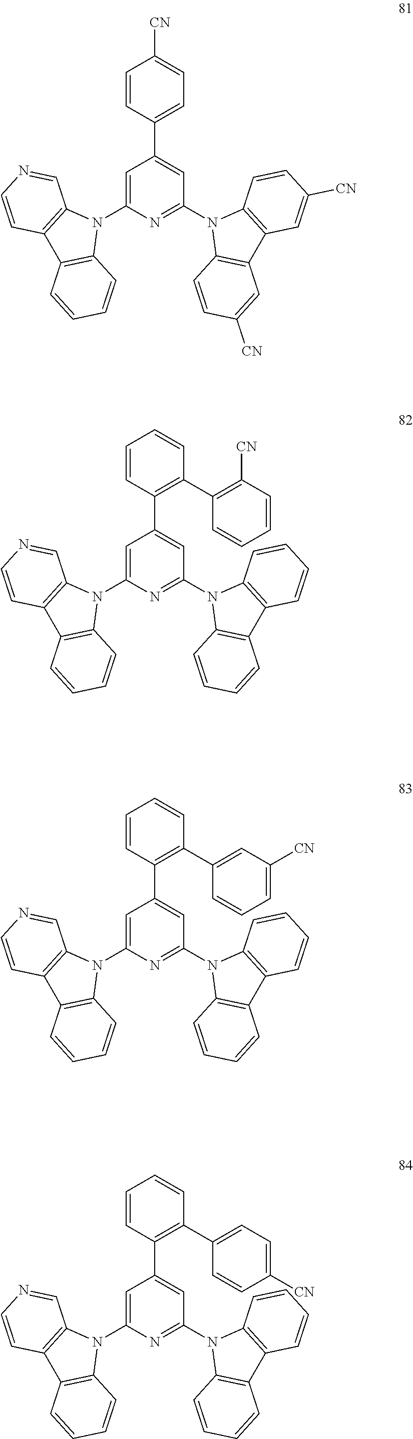 [SMILES: N#Cc1ccc(-c2cc(-n3c4ccc(C#N)cc4c4cc(C#N)ccc43)nc(-n3c4ccccc4c4ccncc43)c2)cc1 ; N#Cc1ccccc1-c1ccccc1-c1cc(-n2c3ccccc3c3ccccc32)nc(-n2c3ccccc3c3ccncc32)c1 ; N#Cc1cccc(-c2ccccc2-c2cc(-n3c4ccccc4c4ccccc43)nc(-n3c4ccccc4c4ccncc43)c2)c1 ; N#Cc1ccc(-c2ccccc2-c2cc(-n3c4ccccc4c4ccccc43)nc(-n3c4ccccc4c4ccncc43)c2)cc1]

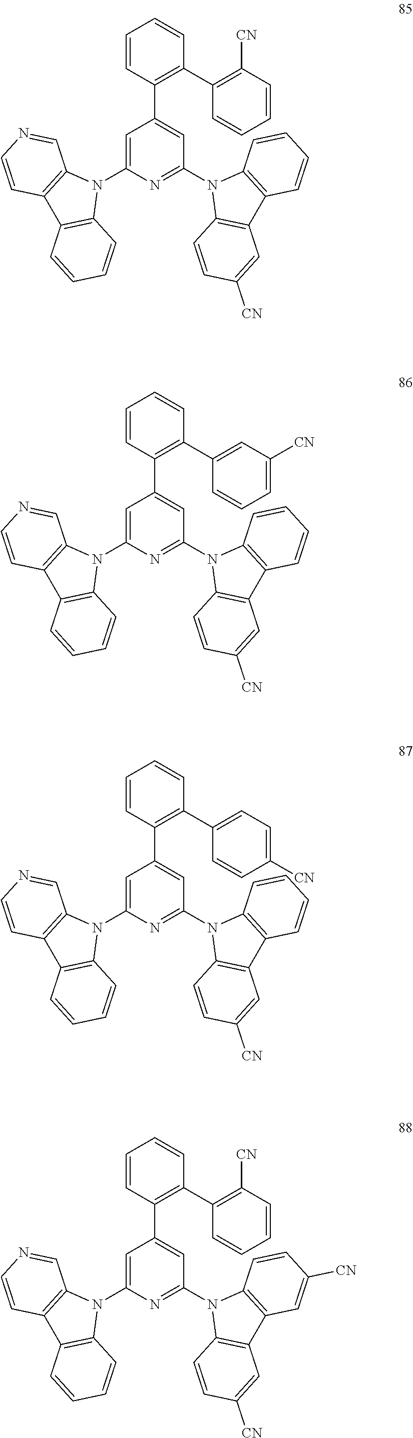 [SMILES: N#Cc1ccc2c(c1)c1ccccc1n2-c1cc(-c2ccccc2-c2ccccc2C#N)cc(-n2c3ccccc3c3ccncc32)n1 ; N#Cc1cccc(-c2ccccc2-c2cc(-n3c4ccccc4c4cc(C#N)ccc43)nc(-n3c4ccccc4c4ccncc43)c2)c1 ; N#Cc1ccc(-c2ccccc2-c2cc(-n3c4ccccc4c4cc(C#N)ccc43)nc(-n3c4ccccc4c4ccncc43)c2)cc1 ; N#Cc1ccc2c(c1)c1cc(C#N)ccc1n2-c1cc(-c2ccccc2-c2ccccc2C#N)cc(-n2c3ccccc3c3ccncc32)n1]

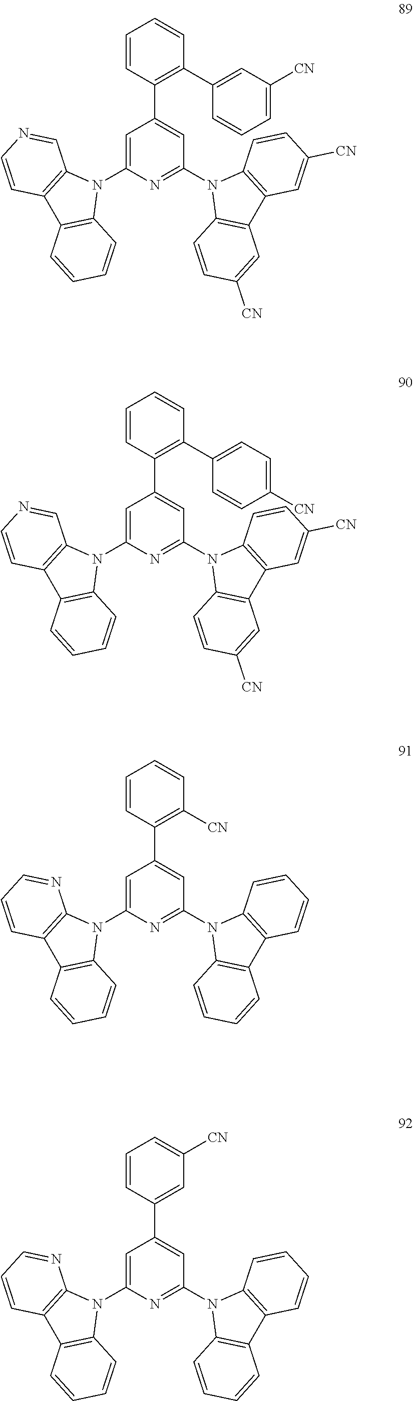 [SMILES: N#Cc1cccc(-c2ccccc2-c2cc(-n3c4ccc(C#N)cc4c4cc(C#N)ccc43)nc(-n3c4ccccc4c4ccncc43)c2)c1 ; N#Cc1ccc(-c2ccccc2-c2cc(-n3c4ccc(C#N)cc4c4cc(C#N)ccc43)nc(-n3c4ccccc4c4ccncc43)c2)cc1 ; N#Cc1ccccc1-c1cc(-n2c3ccccc3c3ccccc32)nc(-n2c3ccccc3c3cccnc32)c1 ; N#Cc1cccc(-c2cc(-n3c4ccccc4c4ccccc43)nc(-n3c4ccccc4c4cccnc43)c2)c1]

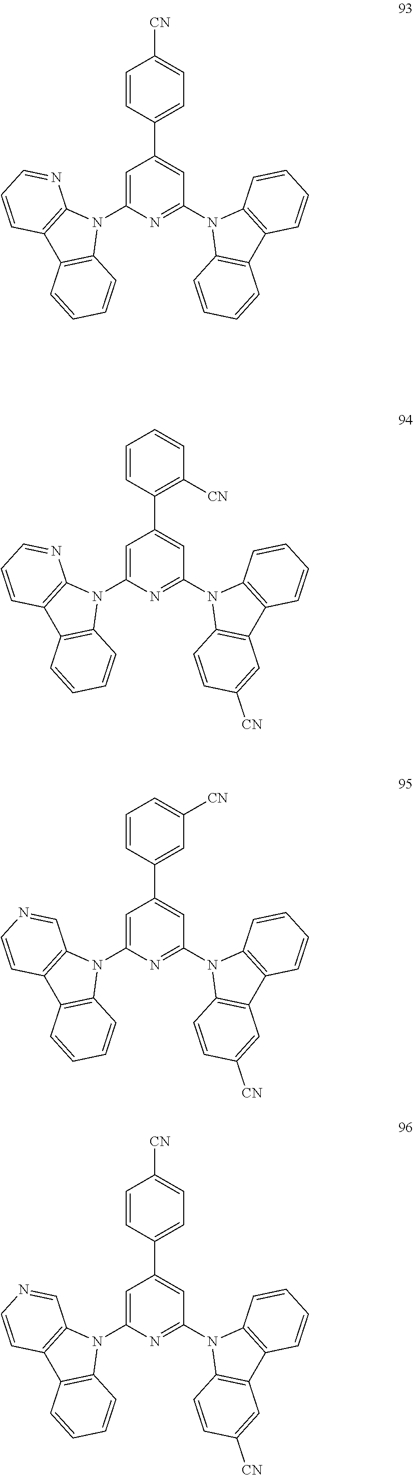 [SMILES: N#Cc1ccc(-c2cc(-n3c4ccccc4c4ccccc43)nc(-n3c4ccccc4c4cccnc43)c2)cc1 ; N#Cc1ccc2c(c1)c1ccccc1n2-c1cc(-c2ccccc2C#N)cc(-n2c3ccccc3c3cccnc32)n1 ; N#Cc1cccc(-c2cc(-n3c4ccccc4c4cc(C#N)ccc43)nc(-n3c4ccccc4c4ccncc43)c2)c1 ; N#Cc1ccc(-c2cc(-n3c4ccccc4c4cc(C#N)ccc43)nc(-n3c4ccccc4c4ccncc43)c2)cc1]

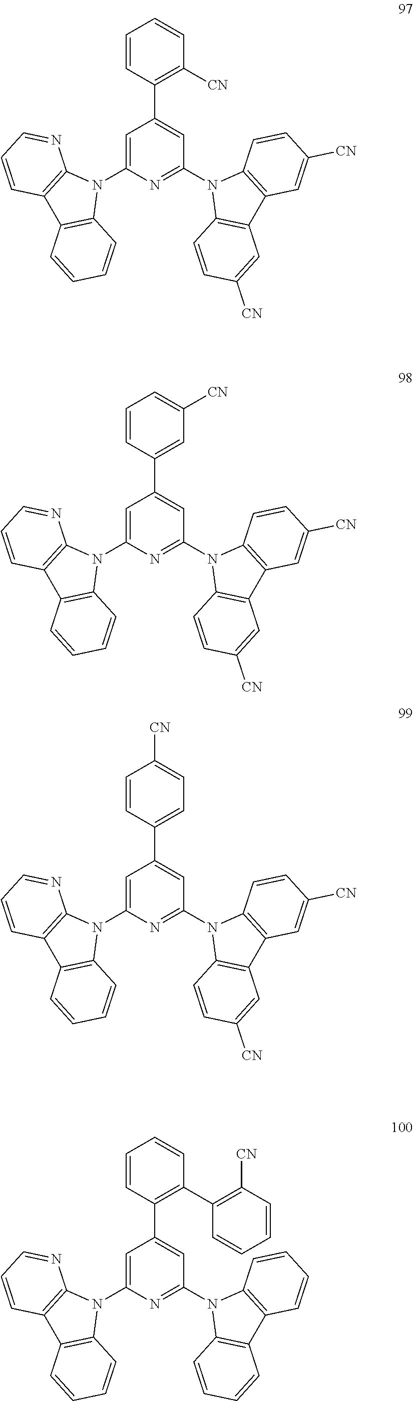 [SMILES: N#Cc1ccc2c(c1)c1cc(C#N)ccc1n2-c1cc(-c2ccccc2C#N)cc(-n2c3ccccc3c3cccnc32)n1 ; N#Cc1cccc(-c2cc(-n3c4ccc(C#N)cc4c4cc(C#N)ccc43)nc(-n3c4ccccc4c4cccnc43)c2)c1 ; N#Cc1ccc(-c2cc(-n3c4ccc(C#N)cc4c4cc(C#N)ccc43)nc(-n3c4ccccc4c4cccnc43)c2)cc1 ; N#Cc1ccccc1-c1ccccc1-c1cc(-n2c3ccccc3c3ccccc32)nc(-n2c3ccccc3c3cccnc32)c1]

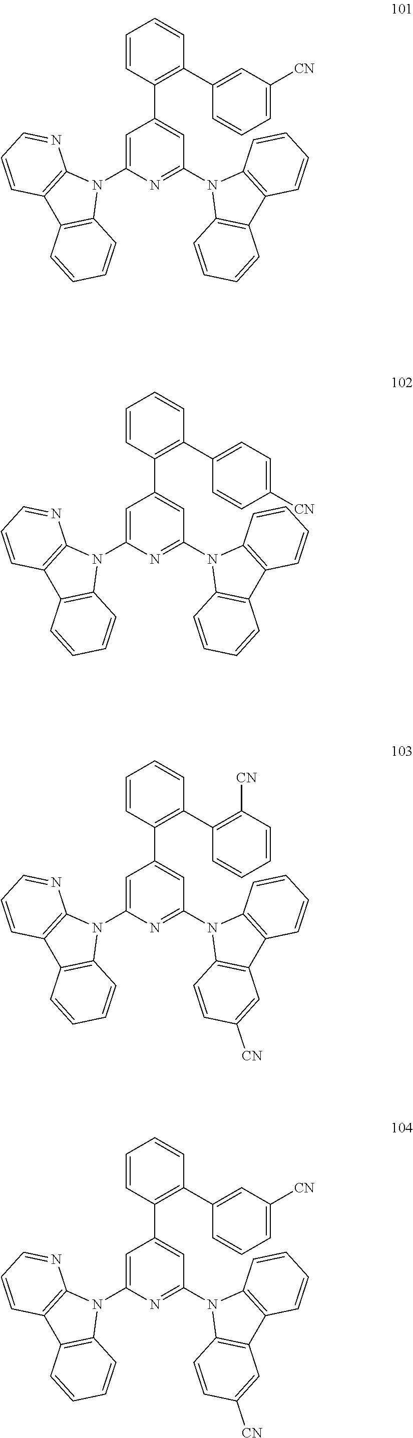 [SMILES: N#Cc1cccc(-c2ccccc2-c2cc(-n3c4ccccc4c4ccccc43)nc(-n3c4ccccc4c4cccnc43)c2)c1 ; N#Cc1ccc(-c2ccccc2-c2cc(-n3c4ccccc4c4ccccc43)nc(-n3c4ccccc4c4cccnc43)c2)cc1 ; N#Cc1ccc2c(c1)c1ccccc1n2-c1cc(-c2ccccc2-c2ccccc2C#N)cc(-n2c3ccccc3c3cccnc32)n1 ; N#Cc1cccc(-c2ccccc2-c2cc(-n3c4ccccc4c4cc(C#N)ccc43)nc(-n3c4ccccc4c4cccnc43)c2)c1]

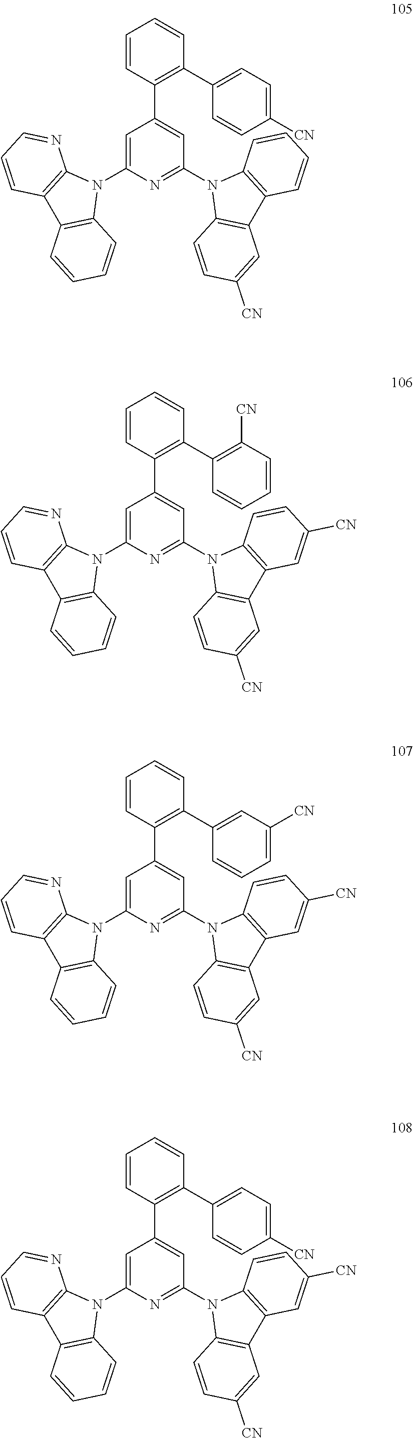 [SMILES: N#Cc1ccc(-c2ccccc2-c2cc(-n3c4ccccc4c4cc(C#N)ccc43)nc(-n3c4ccccc4c4cccnc43)c2)cc1 ; N#Cc1ccc2c(c1)c1cc(C#N)ccc1n2-c1cc(-c2ccccc2-c2ccccc2C#N)cc(-n2c3ccccc3c3cccnc32)n1 ; N#Cc1cccc(-c2ccccc2-c2cc(-n3c4ccc(C#N)cc4c4cc(C#N)ccc43)nc(-n3c4ccccc4c4cccnc43)c2)c1 ; N#Cc1ccc(-c2ccccc2-c2cc(-n3c4ccc(C#N)cc4c4cc(C#N)ccc43)nc(-n3c4ccccc4c4cccnc43)c2)cc1]

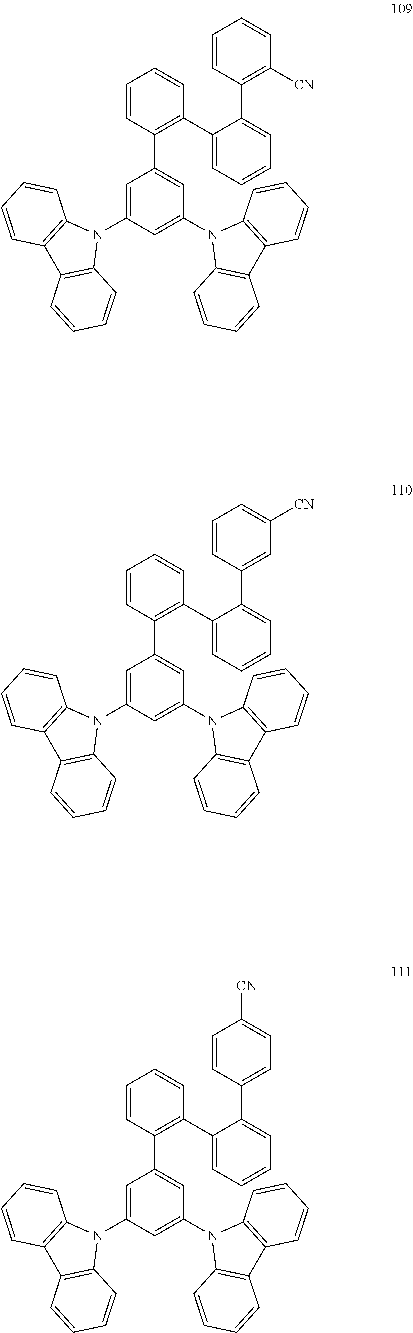 [SMILES: N#Cc1ccccc1-c1ccccc1-c1ccccc1-c1cc(-n2c3ccccc3c3ccccc32)cc(-n2c3ccccc3c3ccccc32)c1 ; N#Cc1cccc(-c2ccccc2-c2ccccc2-c2cc(-n3c4ccccc4c4ccccc43)cc(-n3c4ccccc4c4ccccc43)c2)c1 ; N#Cc1ccc(-c2ccccc2-c2ccccc2-c2cc(-n3c4ccccc4c4ccccc43)cc(-n3c4ccccc4c4ccccc43)c2)cc1]

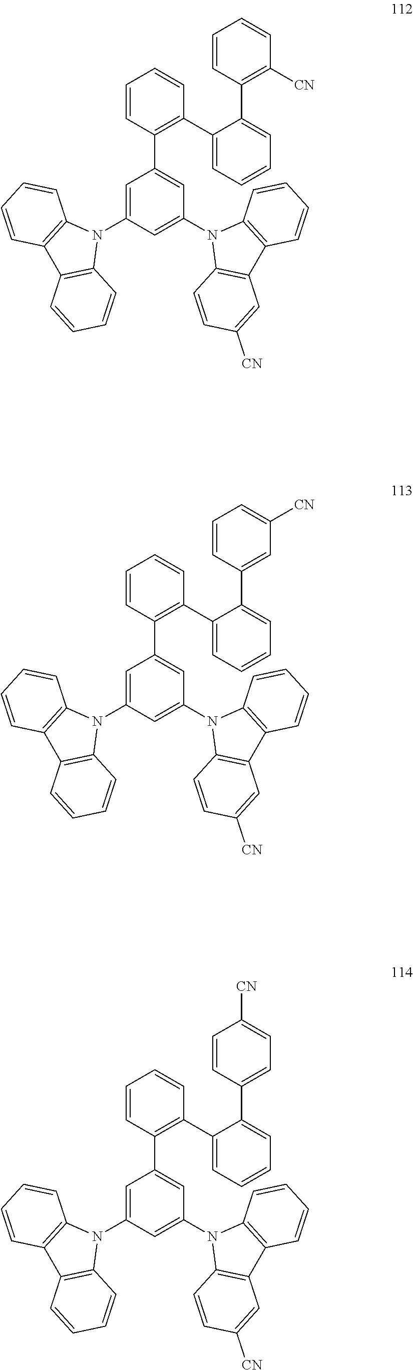 [SMILES: N#Cc1ccc2c(c1)c1ccccc1n2-c1cc(-c2ccccc2-c2ccccc2-c2ccccc2C#N)cc(-n2c3ccccc3c3ccccc32)c1 ; N#Cc1cccc(-c2ccccc2-c2ccccc2-c2cc(-n3c4ccccc4c4ccccc43)cc(-n3c4ccccc4c4cc(C#N)ccc43)c2)c1 ; N#Cc1ccc(-c2ccccc2-c2ccccc2-c2cc(-n3c4ccccc4c4ccccc43)cc(-n3c4ccccc4c4cc(C#N)ccc43)c2)cc1]

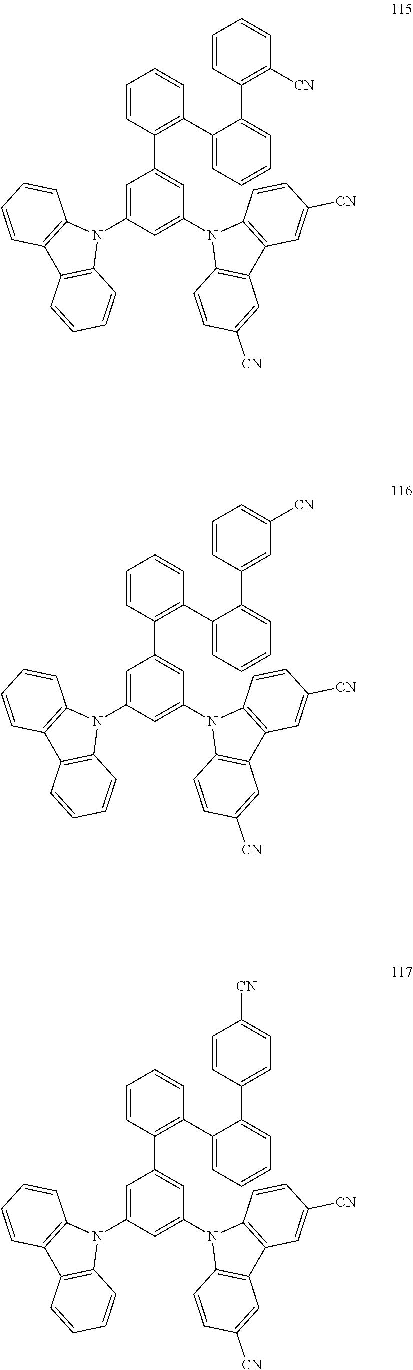 [SMILES: N#Cc1ccc2c(c1)c1cc(C#N)ccc1n2-c1cc(-c2ccccc2-c2ccccc2-c2ccccc2C#N)cc(-n2c3ccccc3c3ccccc32)c1 ; N#Cc1cccc(-c2ccccc2-c2ccccc2-c2cc(-n3c4ccccc4c4ccccc43)cc(-n3c4ccc(C#N)cc4c4cc(C#N)ccc43)c2)c1 ; N#Cc1ccc(-c2ccccc2-c2ccccc2-c2cc(-n3c4ccccc4c4ccccc43)cc(-n3c4ccc(C#N)cc4c4cc(C#N)ccc43)c2)cc1]

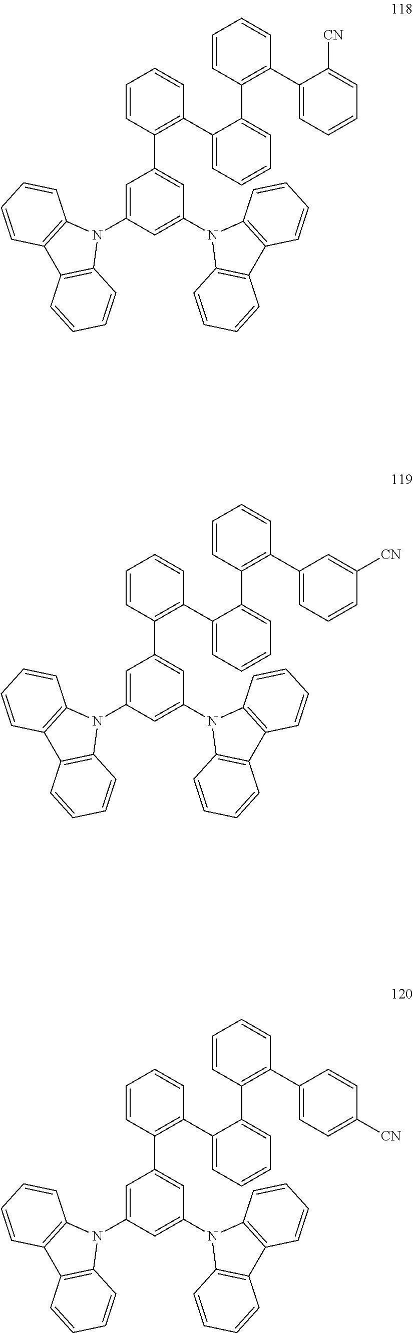 [SMILES: N#Cc1ccccc1-c1ccccc1-c1ccccc1-c1ccccc1-c1cc(-n2c3ccccc3c3ccccc32)cc(-n2c3ccccc3c3ccccc32)c1 ; N#Cc1cccc(-c2ccccc2-c2ccccc2-c2ccccc2-c2cc(-n3c4ccccc4c4ccccc43)cc(-n3c4ccccc4c4ccccc43)c2)c1 ; N#Cc1ccc(-c2ccccc2-c2ccccc2-c2ccccc2-c2cc(-n3c4ccccc4c4ccccc43)cc(-n3c4ccccc4c4ccccc43)c2)cc1]

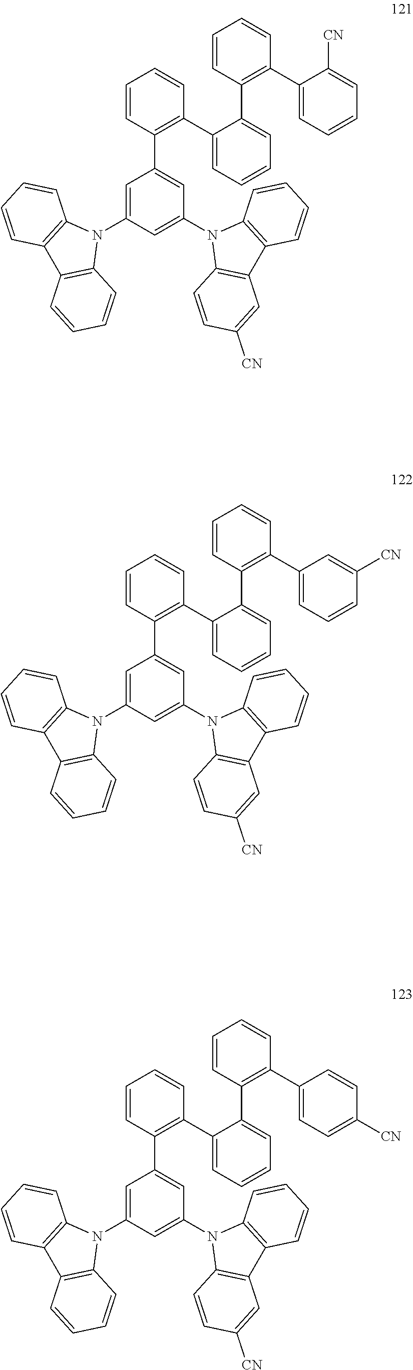 [SMILES: N#Cc1ccc2c(c1)c1ccccc1n2-c1cc(-c2ccccc2-c2ccccc2-c2ccccc2-c2ccccc2C#N)cc(-n2c3ccccc3c3ccccc32)c1 ; N#Cc1cccc(-c2ccccc2-c2ccccc2-c2ccccc2-c2cc(-n3c4ccccc4c4ccccc43)cc(-n3c4ccccc4c4cc(C#N)ccc43)c2)c1 ; N#Cc1ccc(-c2ccccc2-c2ccccc2-c2ccccc2-c2cc(-n3c4ccccc4c4ccccc43)cc(-n3c4ccccc4c4cc(C#N)ccc43)c2)cc1]

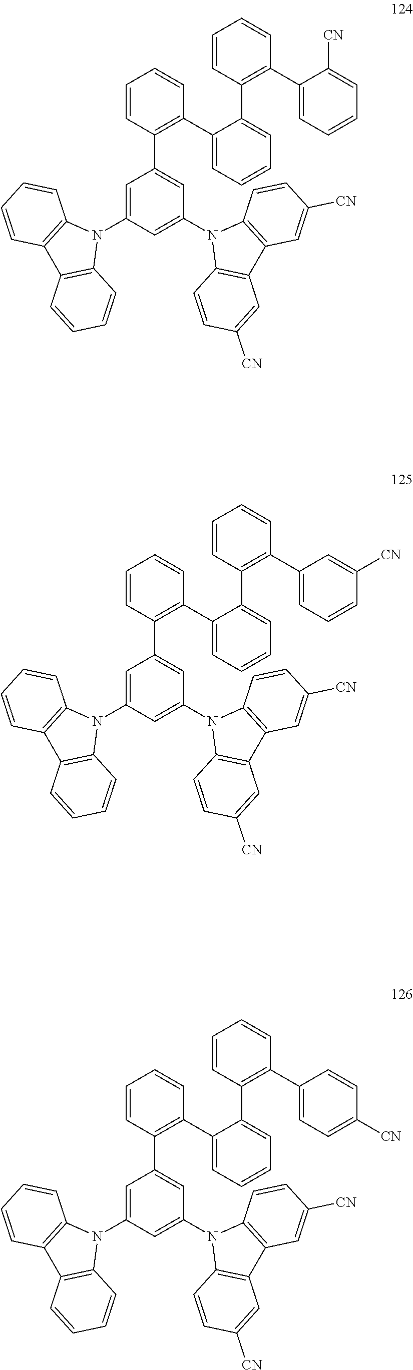 [SMILES: N#Cc1ccc2c(c1)c1cc(C#N)ccc1n2-c1cc(-c2ccccc2-c2ccccc2-c2ccccc2-c2ccccc2C#N)cc(-n2c3ccccc3c3ccccc32)c1 ; N#Cc1cccc(-c2ccccc2-c2ccccc2-c2ccccc2-c2cc(-n3c4ccccc4c4ccccc43)cc(-n3c4ccc(C#N)cc4c4cc(C#N)ccc43)c2)c1 ; N#Cc1ccc(-c2ccccc2-c2ccccc2-c2ccccc2-c2cc(-n3c4ccccc4c4ccccc43)cc(-n3c4ccc(C#N)cc4c4cc(C#N)ccc43)c2)cc1]

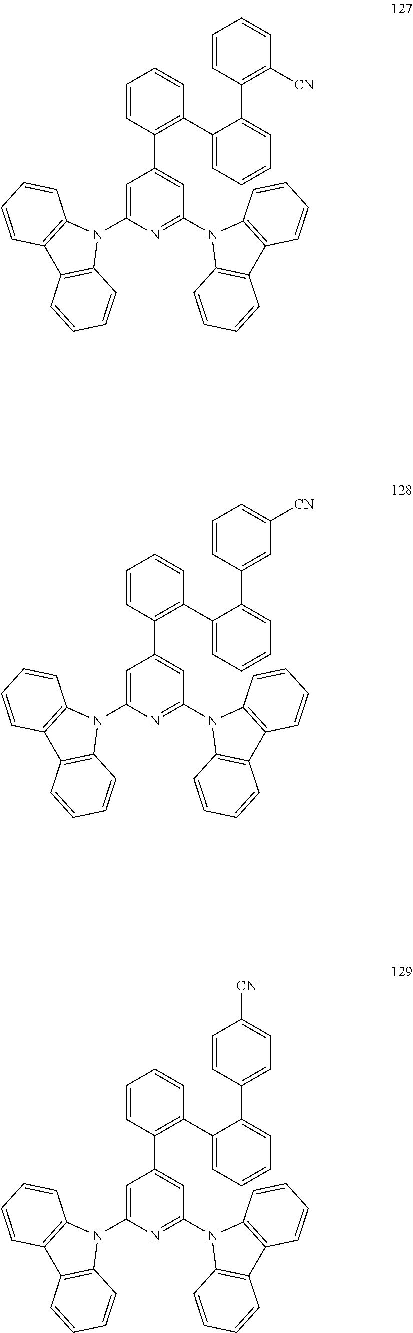 [SMILES: N#Cc1ccccc1-c1ccccc1-c1ccccc1-c1cc(-n2c3ccccc3c3ccccc32)nc(-n2c3ccccc3c3ccccc32)c1 ; N#Cc1cccc(-c2ccccc2-c2ccccc2-c2cc(-n3c4ccccc4c4ccccc43)nc(-n3c4ccccc4c4ccccc43)c2)c1 ; N#Cc1ccc(-c2ccccc2-c2ccccc2-c2cc(-n3c4ccccc4c4ccccc43)nc(-n3c4ccccc4c4ccccc43)c2)cc1]

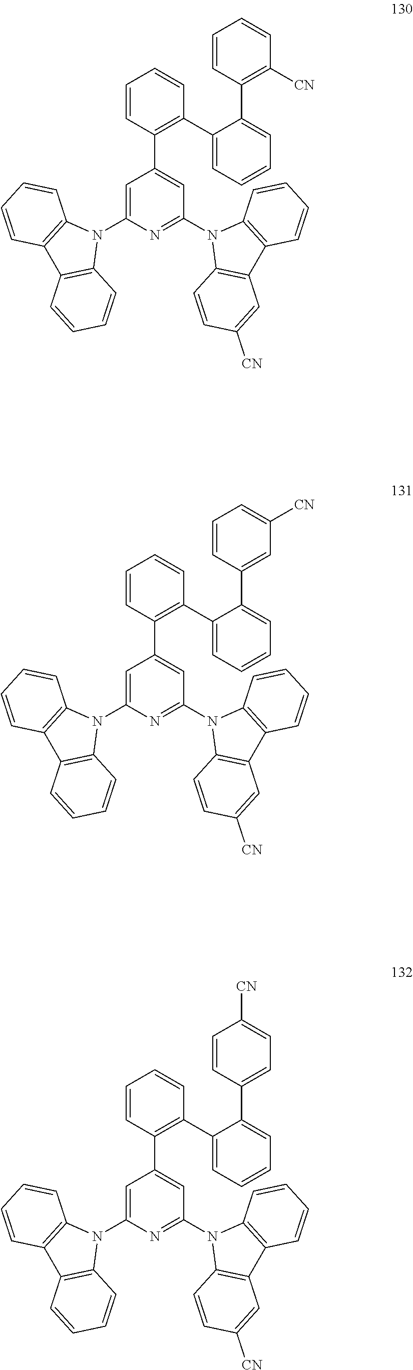 [SMILES: N#Cc1ccc2c(c1)c1ccccc1n2-c1cc(-c2ccccc2-c2ccccc2-c2ccccc2C#N)cc(-n2c3ccccc3c3ccccc32)n1 ; N#Cc1cccc(-c2ccccc2-c2ccccc2-c2cc(-n3c4ccccc4c4ccccc43)nc(-n3c4ccccc4c4cc(C#N)ccc43)c2)c1 ; N#Cc1ccc(-c2ccccc2-c2ccccc2-c2cc(-n3c4ccccc4c4ccccc43)nc(-n3c4ccccc4c4cc(C#N)ccc43)c2)cc1]

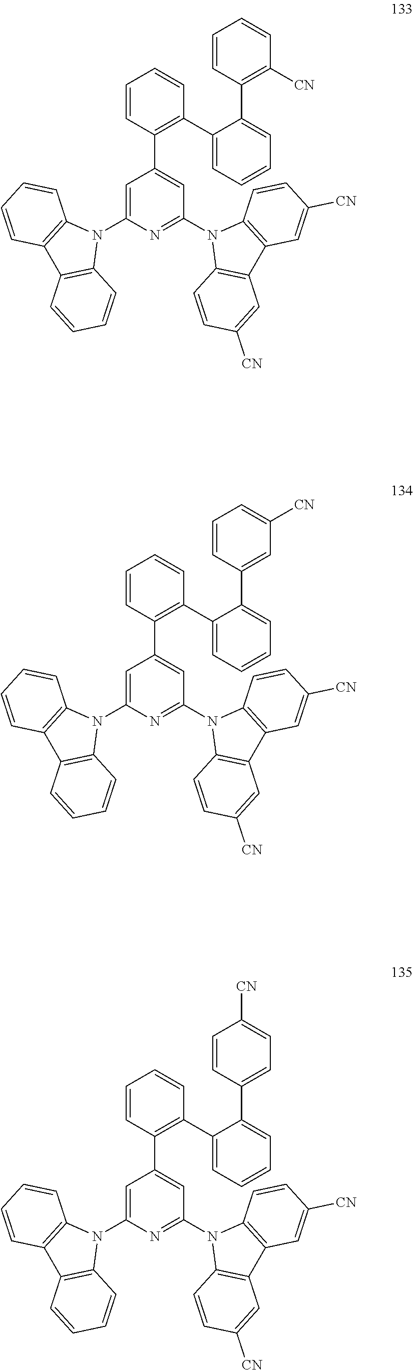 [SMILES: N#Cc1ccc2c(c1)c1cc(C#N)ccc1n2-c1cc(-c2ccccc2-c2ccccc2-c2ccccc2C#N)cc(-n2c3ccccc3c3ccccc32)n1 ; N#Cc1cccc(-c2ccccc2-c2ccccc2-c2cc(-n3c4ccccc4c4ccccc43)nc(-n3c4ccc(C#N)cc4c4cc(C#N)ccc43)c2)c1 ; N#Cc1ccc(-c2ccccc2-c2ccccc2-c2cc(-n3c4ccccc4c4ccccc43)nc(-n3c4ccc(C#N)cc4c4cc(C#N)ccc43)c2)cc1]

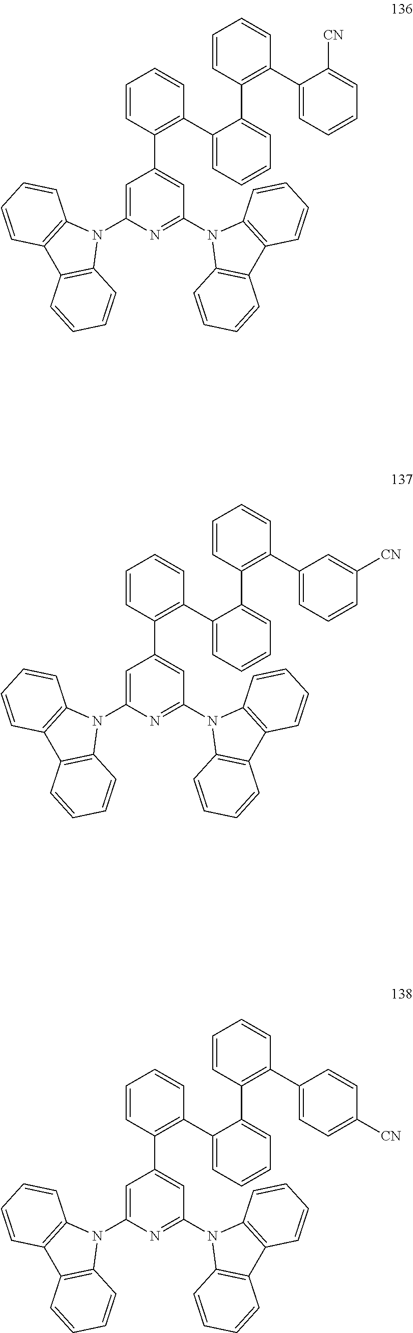 [SMILES: N#Cc1ccccc1-c1ccccc1-c1ccccc1-c1ccccc1-c1cc(-n2c3ccccc3c3ccccc32)nc(-n2c3ccccc3c3ccccc32)c1 ; N#Cc1cccc(-c2ccccc2-c2ccccc2-c2ccccc2-c2cc(-n3c4ccccc4c4ccccc43)nc(-n3c4ccccc4c4ccccc43)c2)c1 ; N#Cc1ccc(-c2ccccc2-c2ccccc2-c2ccccc2-c2cc(-n3c4ccccc4c4ccccc43)nc(-n3c4ccccc4c4ccccc43)c2)cc1]

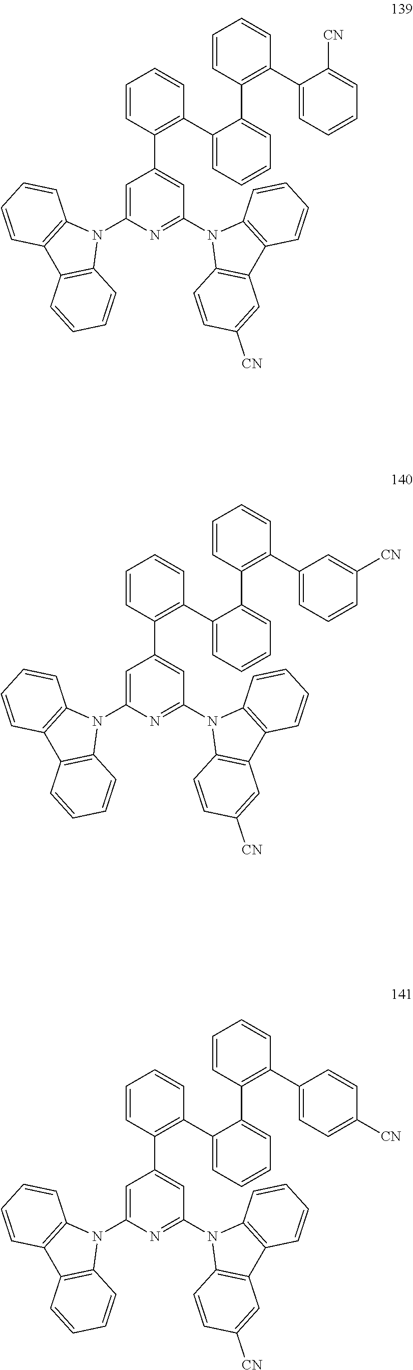 [SMILES: N#Cc1ccc2c(c1)c1ccccc1n2-c1cc(-c2ccccc2-c2ccccc2-c2ccccc2-c2ccccc2C#N)cc(-n2c3ccccc3c3ccccc32)n1 ; N#Cc1cccc(-c2ccccc2-c2ccccc2-c2ccccc2-c2cc(-n3c4ccccc4c4ccccc43)nc(-n3c4ccccc4c4cc(C#N)ccc43)c2)c1 ; N#Cc1ccc(-c2ccccc2-c2ccccc2-c2ccccc2-c2cc(-n3c4ccccc4c4ccccc43)nc(-n3c4ccccc4c4cc(C#N)ccc43)c2)cc1]

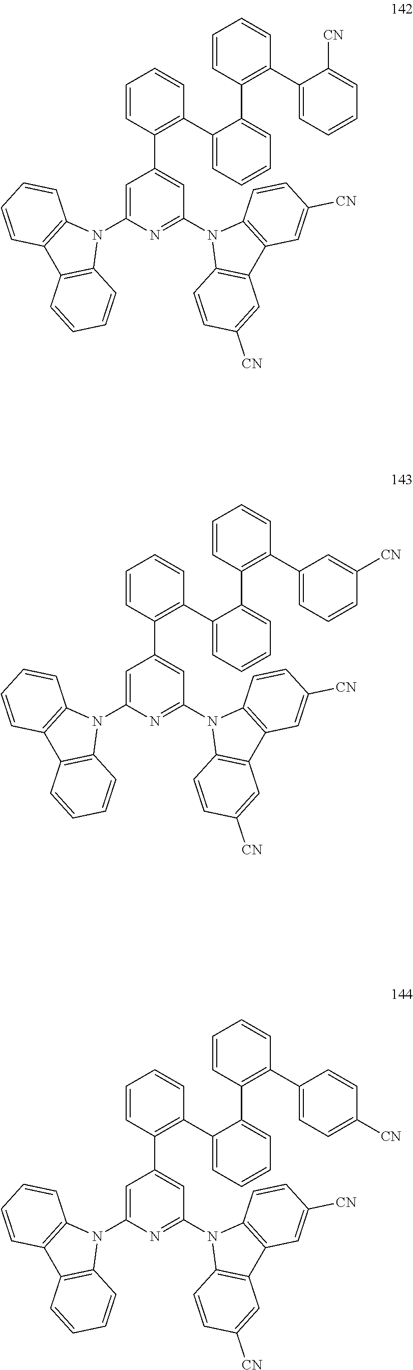 [SMILES: N#Cc1ccc2c(c1)c1cc(C#N)ccc1n2-c1cc(-c2ccccc2-c2ccccc2-c2ccccc2-c2ccccc2C#N)cc(-n2c3ccccc3c3ccccc32)n1 ; N#Cc1cccc(-c2ccccc2-c2ccccc2-c2ccccc2-c2cc(-n3c4ccccc4c4ccccc43)nc(-n3c4ccc(C#N)cc4c4cc(C#N)ccc43)c2)c1 ; N#Cc1ccc(-c2ccccc2-c2ccccc2-c2ccccc2-c2cc(-n3c4ccccc4c4ccccc43)nc(-n3c4ccc(C#N)cc4c4cc(C#N)ccc43)c2)cc1]

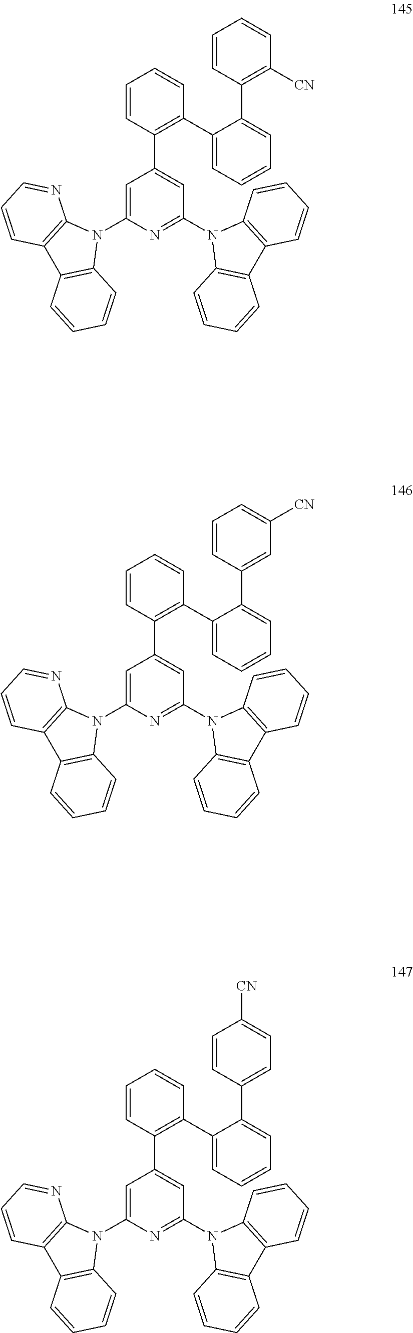 [SMILES: N#Cc1ccccc1-c1ccccc1-c1ccccc1-c1cc(-n2c3ccccc3c3ccccc32)nc(-n2c3ccccc3c3cccnc32)c1 ; N#Cc1cccc(-c2ccccc2-c2ccccc2-c2cc(-n3c4ccccc4c4ccccc43)nc(-n3c4ccccc4c4cccnc43)c2)c1 ; N#Cc1ccc(-c2ccccc2-c2ccccc2-c2cc(-n3c4ccccc4c4ccccc43)nc(-n3c4ccccc4c4cccnc43)c2)cc1]

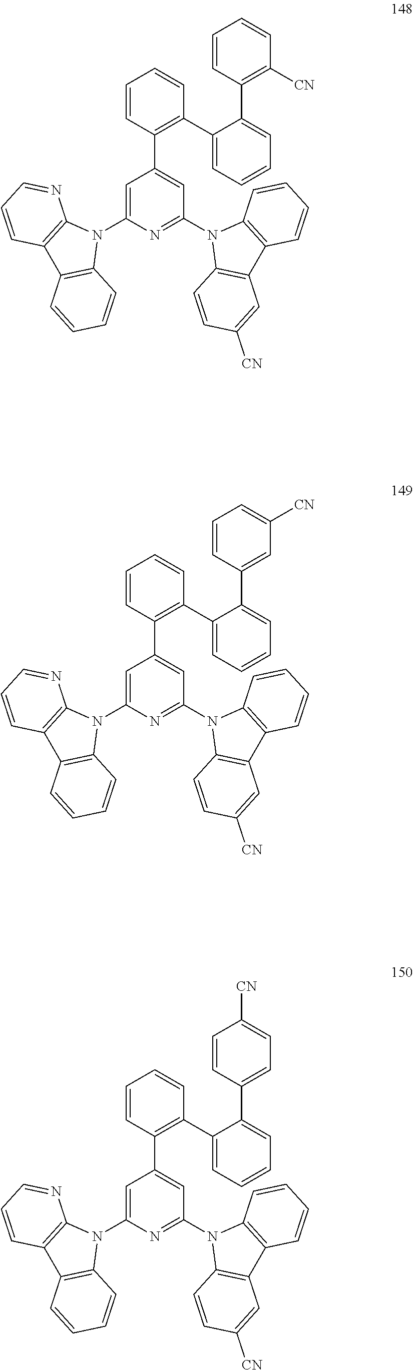 [SMILES: N#Cc1ccc2c(c1)c1ccccc1n2-c1cc(-c2ccccc2-c2ccccc2-c2ccccc2C#N)cc(-n2c3ccccc3c3cccnc32)n1 ; N#Cc1cccc(-c2ccccc2-c2ccccc2-c2cc(-n3c4ccccc4c4cc(C#N)ccc43)nc(-n3c4ccccc4c4cccnc43)c2)c1 ; N#Cc1ccc(-c2ccccc2-c2ccccc2-c2cc(-n3c4ccccc4c4cc(C#N)ccc43)nc(-n3c4ccccc4c4cccnc43)c2)cc1]

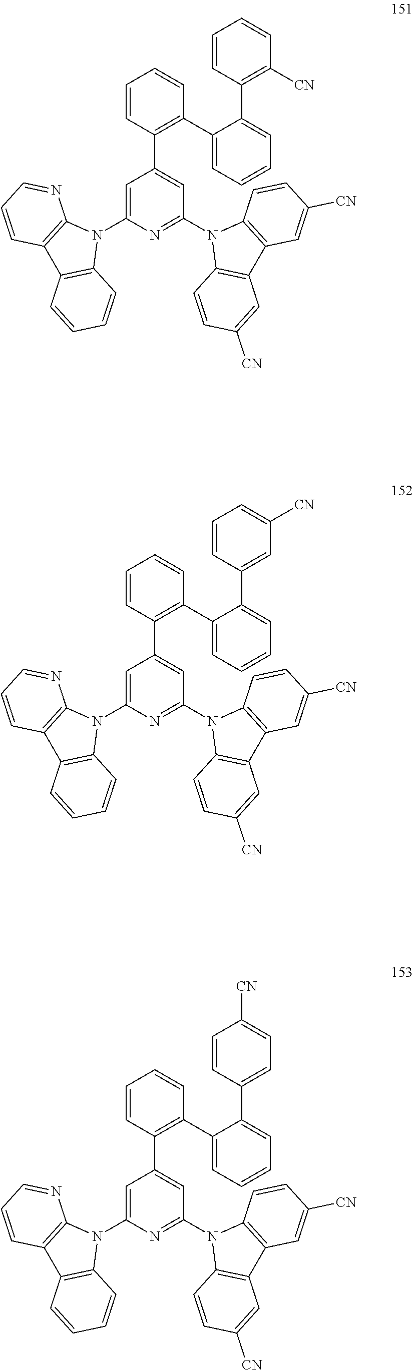 [SMILES: N#Cc1ccc2c(c1)c1cc(C#N)ccc1n2-c1cc(-c2ccccc2-c2ccccc2-c2ccccc2C#N)cc(-n2c3ccccc3c3cccnc32)n1 ; N#Cc1cccc(-c2ccccc2-c2ccccc2-c2cc(-n3c4ccc(C#N)cc4c4cc(C#N)ccc43)nc(-n3c4ccccc4c4cccnc43)c2)c1 ; N#Cc1ccc(-c2ccccc2-c2ccccc2-c2cc(-n3c4ccc(C#N)cc4c4cc(C#N)ccc43)nc(-n3c4ccccc4c4cccnc43)c2)cc1]

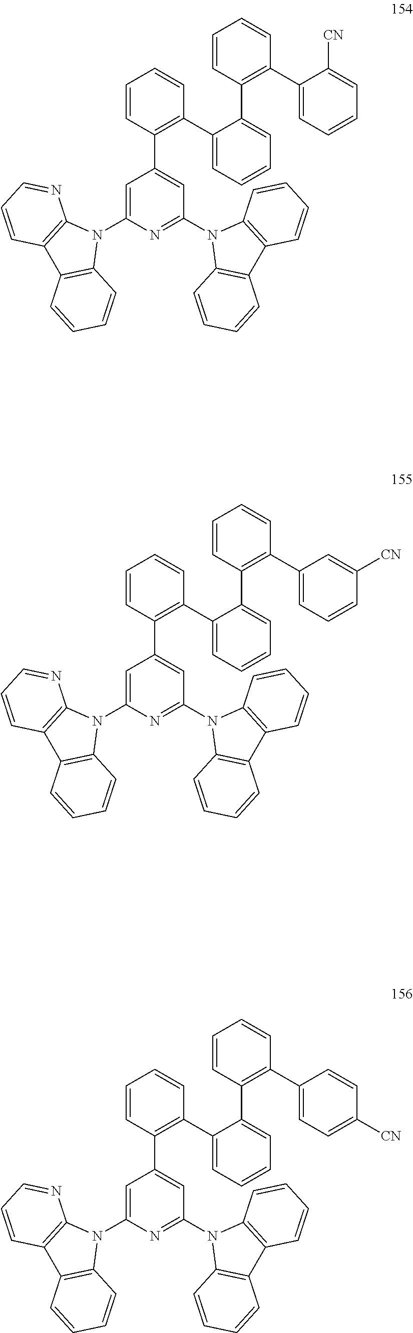 [SMILES: N#Cc1ccccc1-c1ccccc1-c1ccccc1-c1ccccc1-c1cc(-n2c3ccccc3c3ccccc32)nc(-n2c3ccccc3c3cccnc32)c1 ; N#Cc1cccc(-c2ccccc2-c2ccccc2-c2ccccc2-c2cc(-n3c4ccccc4c4ccccc43)nc(-n3c4ccccc4c4cccnc43)c2)c1 ; N#Cc1ccc(-c2ccccc2-c2ccccc2-c2ccccc2-c2cc(-n3c4ccccc4c4ccccc43)nc(-n3c4ccccc4c4cccnc43)c2)cc1]

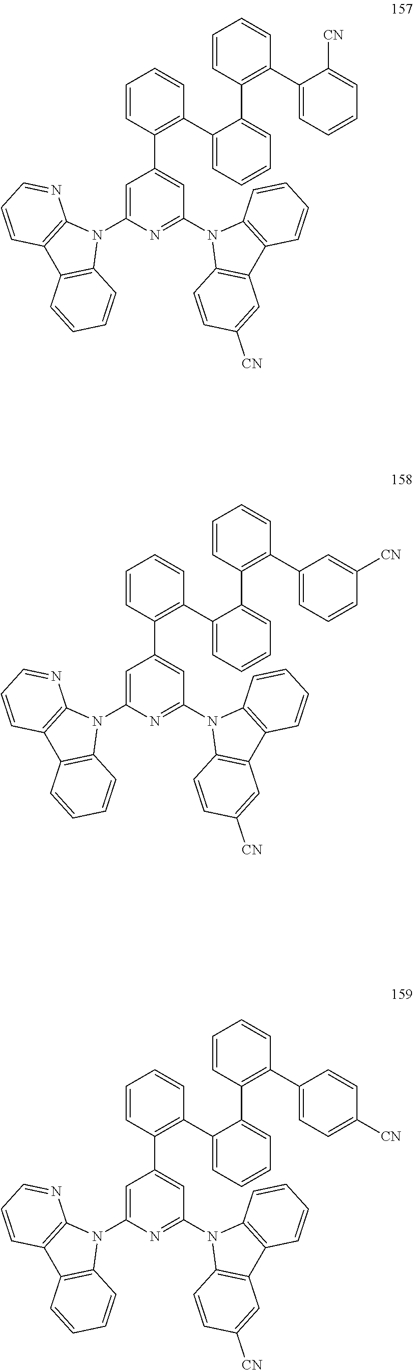 [SMILES: N#Cc1ccc2c(c1)c1ccccc1n2-c1cc(-c2ccccc2-c2ccccc2-c2ccccc2-c2ccccc2C#N)cc(-n2c3ccccc3c3cccnc32)n1 ; N#Cc1cccc(-c2ccccc2-c2ccccc2-c2ccccc2-c2cc(-n3c4ccccc4c4cc(C#N)ccc43)nc(-n3c4ccccc4c4cccnc43)c2)c1 ; N#Cc1ccc(-c2ccccc2-c2ccccc2-c2ccccc2-c2cc(-n3c4ccccc4c4cc(C#N)ccc43)nc(-n3c4ccccc4c4cccnc43)c2)cc1]

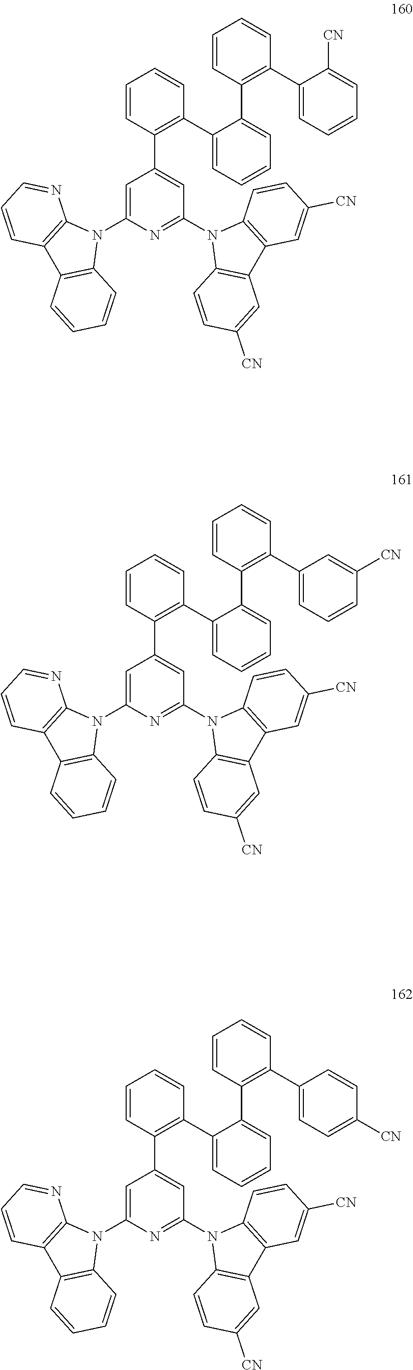 [SMILES: N#Cc1ccc2c(c1)c1cc(C#N)ccc1n2-c1cc(-c2ccccc2-c2ccccc2-c2ccccc2-c2ccccc2C#N)cc(-n2c3ccccc3c3cccnc32)n1 ; N#Cc1cccc(-c2ccccc2-c2ccccc2-c2ccccc2-c2cc(-n3c4ccc(C#N)cc4c4cc(C#N)ccc43)nc(-n3c4ccccc4c4cccnc43)c2)c1 ; N#Cc1ccc(-c2ccccc2-c2ccccc2-c2ccccc2-c2cc(-n3c4ccc(C#N)cc4c4cc(C#N)ccc43)nc(-n3c4ccccc4c4cccnc43)c2)cc1]

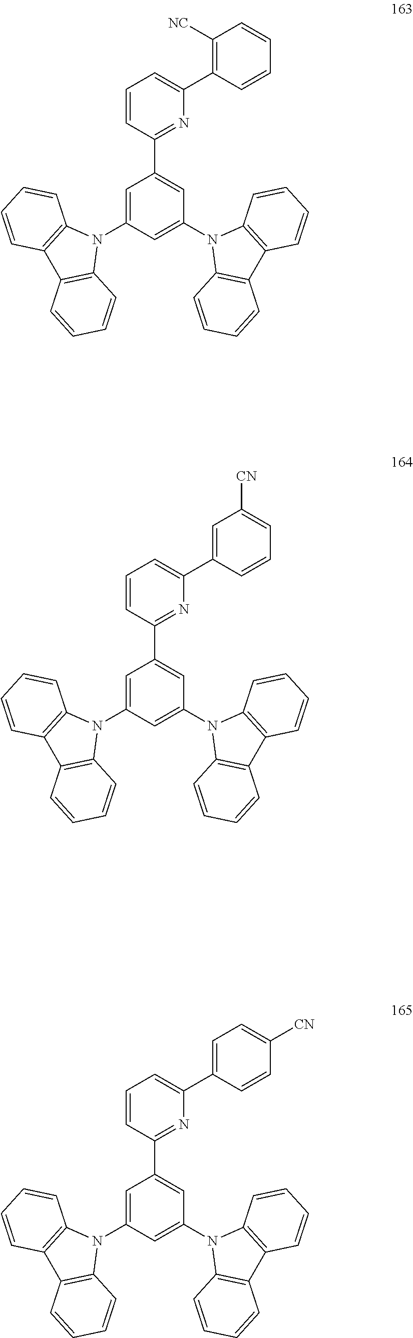 [SMILES: N#Cc1ccccc1-c1cccc(-c2cc(-n3c4ccccc4c4ccccc43)cc(-n3c4ccccc4c4ccccc43)c2)n1 ; N#Cc1cccc(-c2cccc(-c3cc(-n4c5ccccc5c5ccccc54)cc(-n4c5ccccc5c5ccccc54)c3)n2)c1 ; N#Cc1ccc(-c2cccc(-c3cc(-n4c5ccccc5c5ccccc54)cc(-n4c5ccccc5c5ccccc54)c3)n2)cc1]

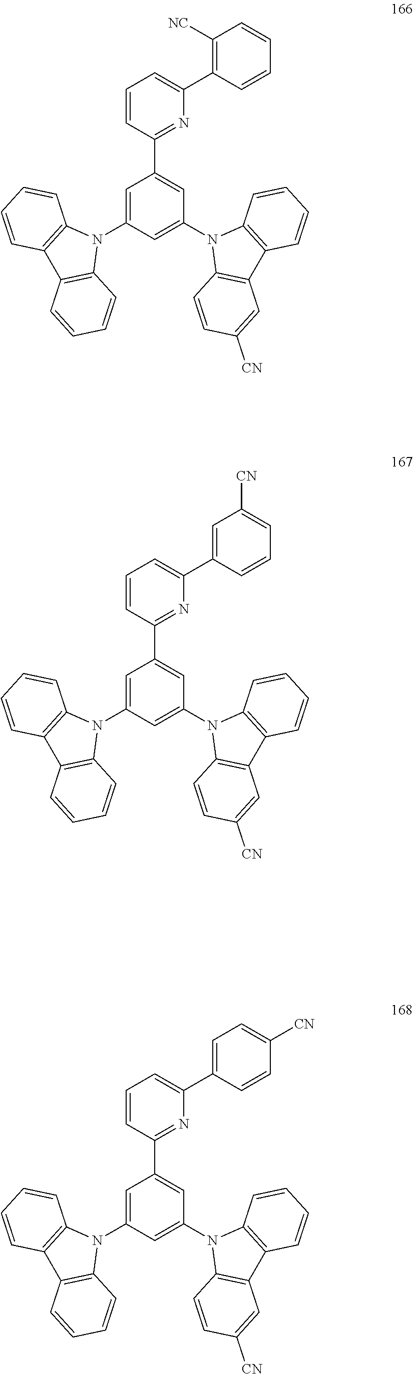 [SMILES: N#Cc1ccc2c(c1)c1ccccc1n2-c1cc(-c2cccc(-c3ccccc3C#N)n2)cc(-n2c3ccccc3c3ccccc32)c1 ; N#Cc1cccc(-c2cccc(-c3cc(-n4c5ccccc5c5ccccc54)cc(-n4c5ccccc5c5cc(C#N)ccc54)c3)n2)c1 ; N#Cc1ccc(-c2cccc(-c3cc(-n4c5ccccc5c5ccccc54)cc(-n4c5ccccc5c5cc(C#N)ccc54)c3)n2)cc1]

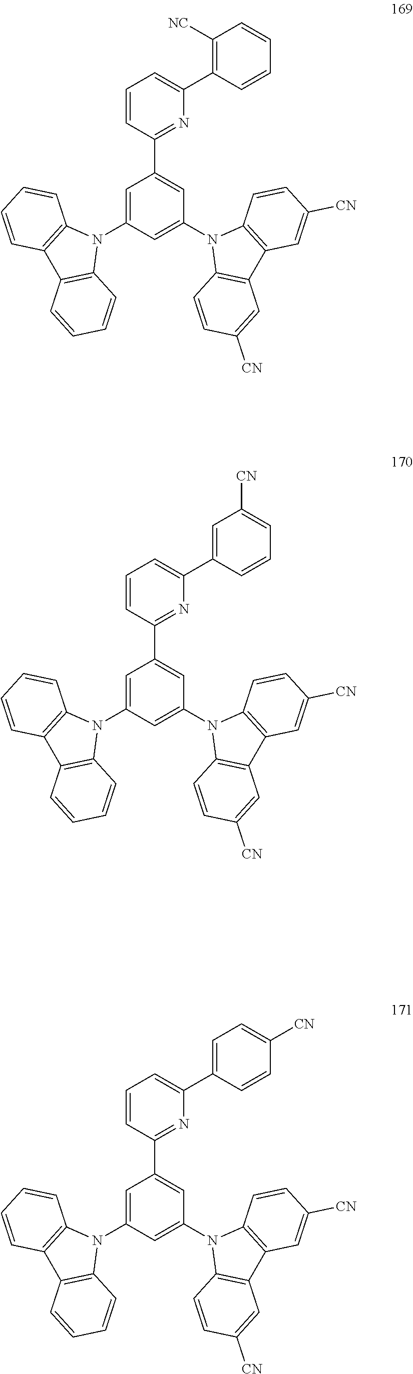 [SMILES: N#Cc1ccc2c(c1)c1cc(C#N)ccc1n2-c1cc(-c2cccc(-c3ccccc3C#N)n2)cc(-n2c3ccccc3c3ccccc32)c1 ; N#Cc1cccc(-c2cccc(-c3cc(-n4c5ccccc5c5ccccc54)cc(-n4c5ccc(C#N)cc5c5cc(C#N)ccc54)c3)n2)c1 ; N#Cc1ccc(-c2cccc(-c3cc(-n4c5ccccc5c5ccccc54)cc(-n4c5ccc(C#N)cc5c5cc(C#N)ccc54)c3)n2)cc1]

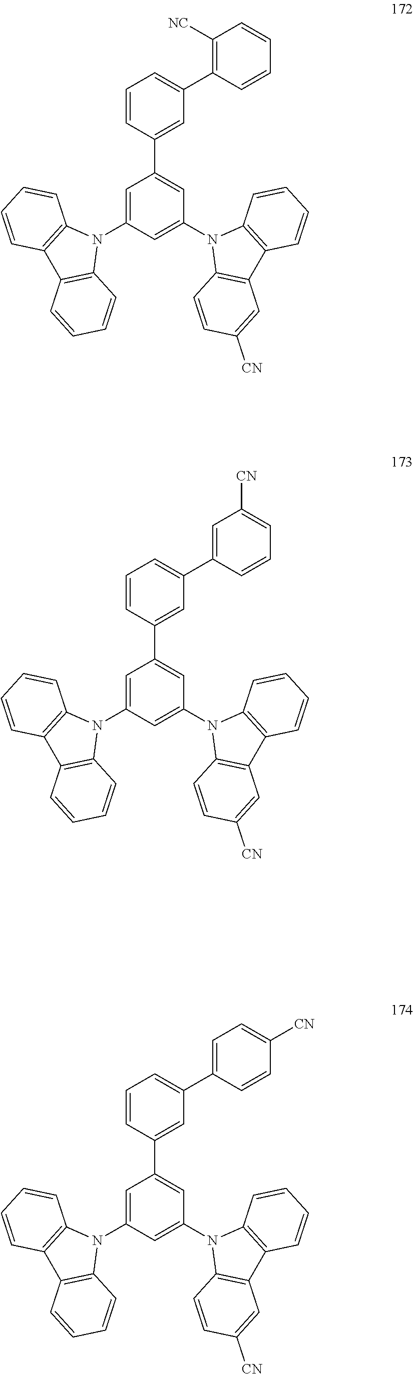 [SMILES: N#Cc1ccc2c(c1)c1ccccc1n2-c1cc(-c2cccc(-c3ccccc3C#N)c2)cc(-n2c3ccccc3c3ccccc32)c1 ; N#Cc1cccc(-c2cccc(-c3cc(-n4c5ccccc5c5ccccc54)cc(-n4c5ccccc5c5cc(C#N)ccc54)c3)c2)c1 ; N#Cc1ccc(-c2cccc(-c3cc(-n4c5ccccc5c5ccccc54)cc(-n4c5ccccc5c5cc(C#N)ccc54)c3)c2)cc1]

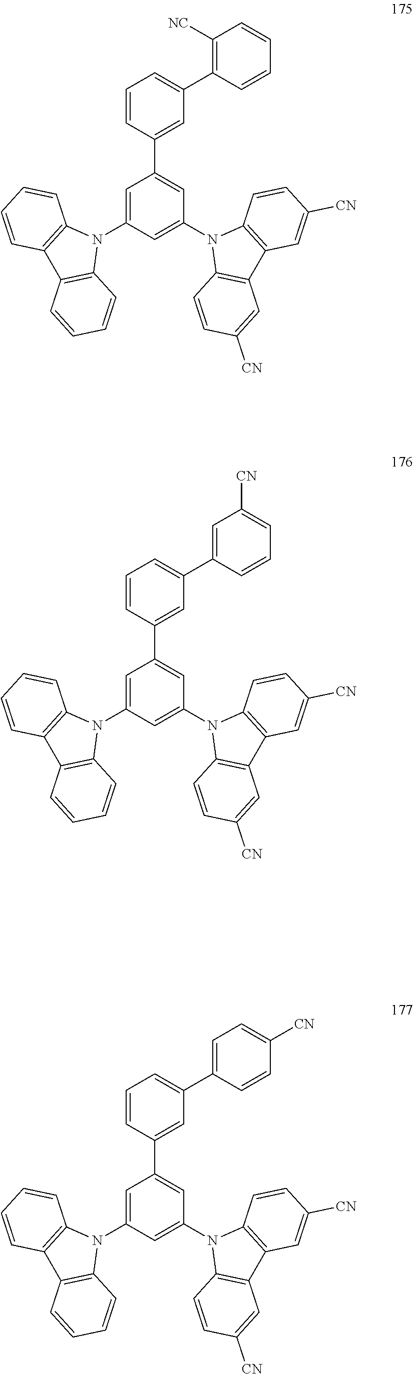 [SMILES: N#Cc1ccc2c(c1)c1cc(C#N)ccc1n2-c1cc(-c2cccc(-c3ccccc3C#N)c2)cc(-n2c3ccccc3c3ccccc32)c1 ; N#Cc1cccc(-c2cccc(-c3cc(-n4c5ccccc5c5ccccc54)cc(-n4c5ccc(C#N)cc5c5cc(C#N)ccc54)c3)c2)c1 ; N#Cc1ccc(-c2cccc(-c3cc(-n4c5ccccc5c5ccccc54)cc(-n4c5ccc(C#N)cc5c5cc(C#N)ccc54)c3)c2)cc1]

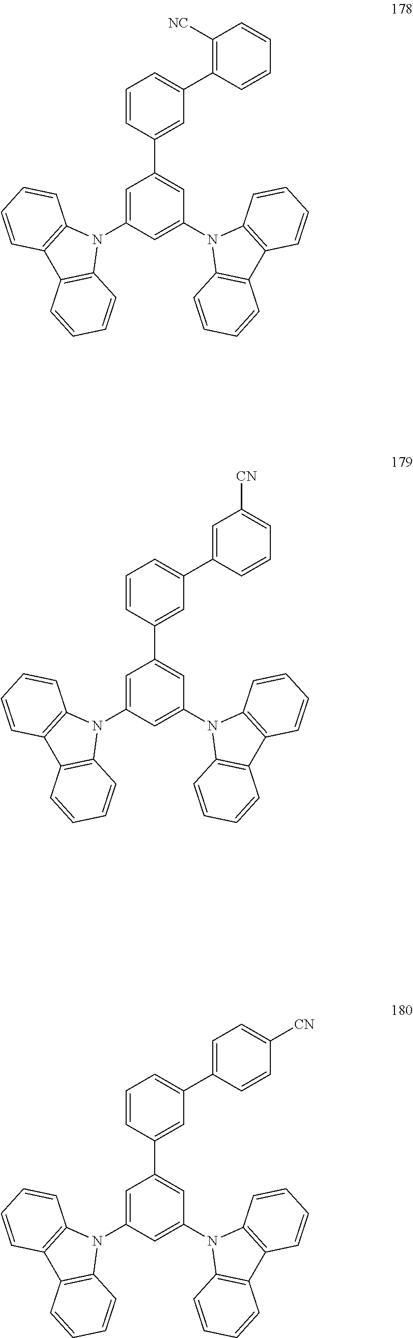 [SMILES: N#Cc1ccccc1-c1cccc(-c2cc(-n3c4ccccc4c4ccccc43)cc(-n3c4ccccc4c4ccccc43)c2)c1 ; N#Cc1cccc(-c2cccc(-c3cc(-n4c5ccccc5c5ccccc54)cc(-n4c5ccccc5c5ccccc54)c3)c2)c1 ; N#Cc1ccc(-c2cccc(-c3cc(-n4c5ccccc5c5ccccc54)cc(-n4c5ccccc5c5ccccc54)c3)c2)cc1]

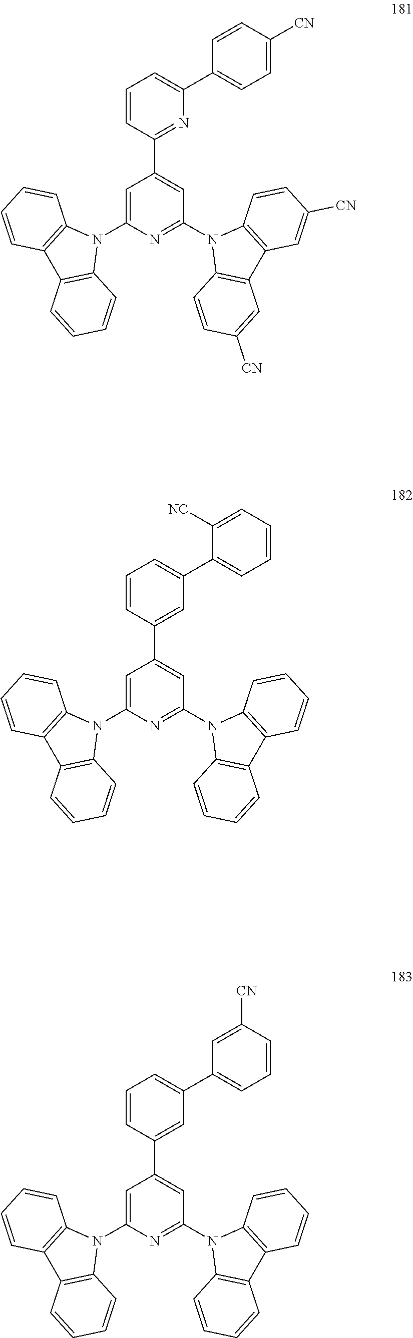 [SMILES: N#Cc1ccc(-c2cccc(-c3cc(-n4c5ccccc5c5ccccc54)nc(-n4c5ccc(C#N)cc5c5cc(C#N)ccc54)c3)n2)cc1 ; N#Cc1ccccc1-c1cccc(-c2cc(-n3c4ccccc4c4ccccc43)nc(-n3c4ccccc4c4ccccc43)c2)c1 ; N#Cc1cccc(-c2cccc(-c3cc(-n4c5ccccc5c5ccccc54)nc(-n4c5ccccc5c5ccccc54)c3)c2)c1]

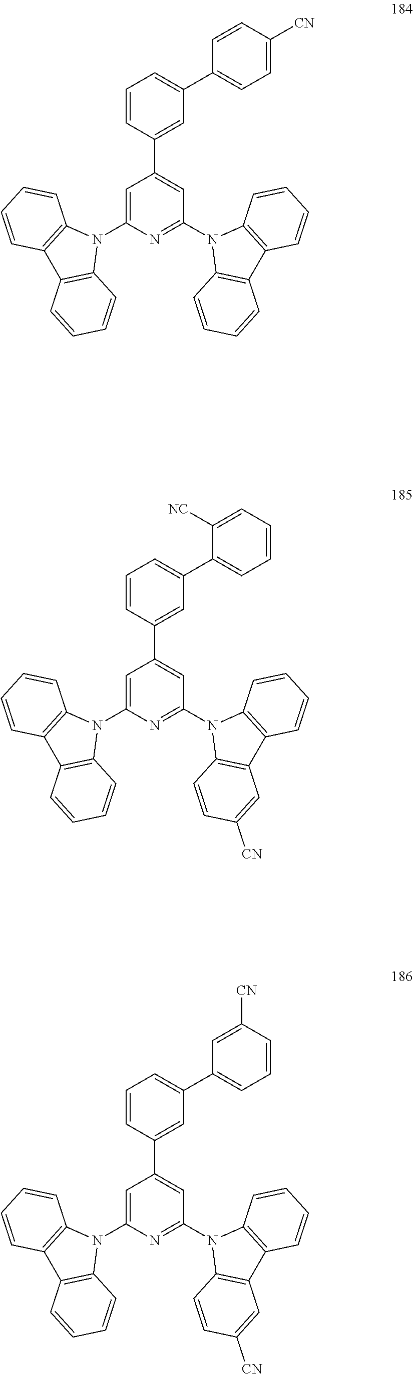 [SMILES: N#Cc1ccc(-c2cccc(-c3cc(-n4c5ccccc5c5ccccc54)nc(-n4c5ccccc5c5ccccc54)c3)c2)cc1 ; N#Cc1ccc2c(c1)c1ccccc1n2-c1cc(-c2cccc(-c3ccccc3C#N)c2)cc(-n2c3ccccc3c3ccccc32)n1 ; N#Cc1cccc(-c2cccc(-c3cc(-n4c5ccccc5c5ccccc54)nc(-n4c5ccccc5c5cc(C#N)ccc54)c3)c2)c1]

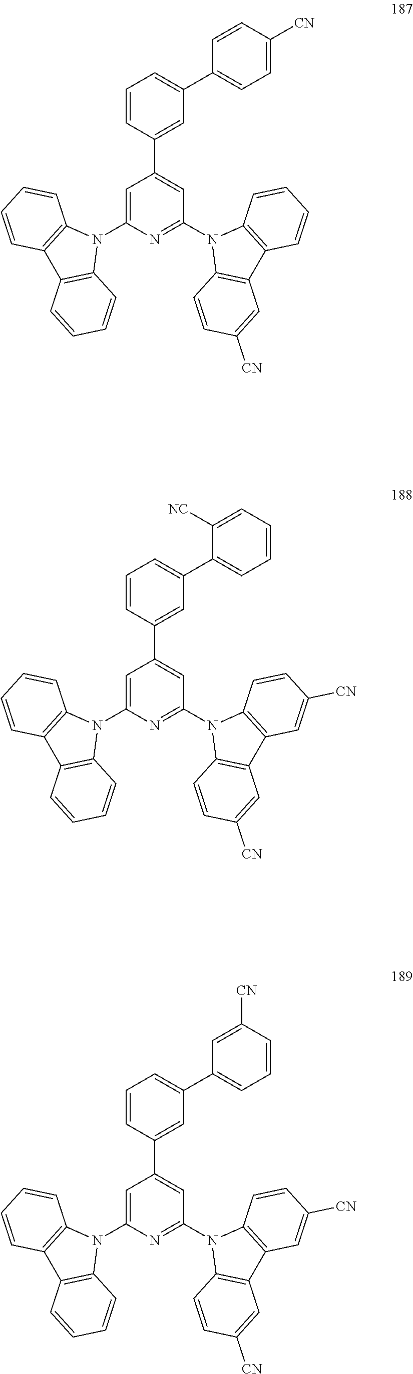 [SMILES: N#Cc1ccc(-c2cccc(-c3cc(-n4c5ccccc5c5ccccc54)nc(-n4c5ccccc5c5cc(C#N)ccc54)c3)c2)cc1 ; N#Cc1ccc2c(c1)c1cc(C#N)ccc1n2-c1cc(-c2cccc(-c3ccccc3C#N)c2)cc(-n2c3ccccc3c3ccccc32)n1 ; N#Cc1cccc(-c2cccc(-c3cc(-n4c5ccccc5c5ccccc54)nc(-n4c5ccc(C#N)cc5c5cc(C#N)ccc54)c3)c2)c1]

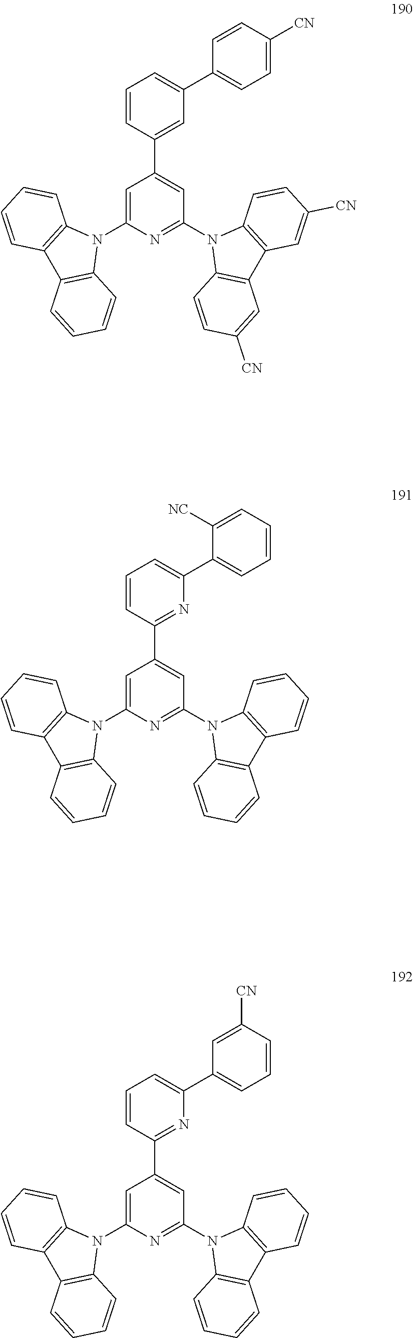 [SMILES: N#Cc1ccc(-c2cccc(-c3cc(-n4c5ccccc5c5ccccc54)nc(-n4c5ccc(C#N)cc5c5cc(C#N)ccc54)c3)c2)cc1 ; N#Cc1ccccc1-c1cccc(-c2cc(-n3c4ccccc4c4ccccc43)nc(-n3c4ccccc4c4ccccc43)c2)n1 ; N#Cc1cccc(-c2cccc(-c3cc(-n4c5ccccc5c5ccccc54)nc(-n4c5ccccc5c5ccccc54)c3)n2)c1]

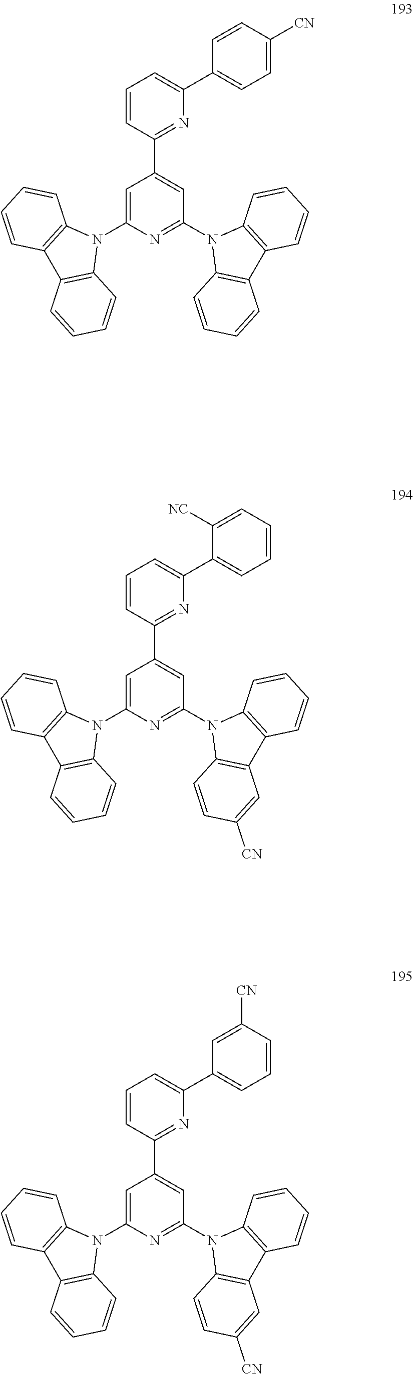 [SMILES: N#Cc1ccc(-c2cccc(-c3cc(-n4c5ccccc5c5ccccc54)nc(-n4c5ccccc5c5ccccc54)c3)n2)cc1 ; N#Cc1ccc2c(c1)c1ccccc1n2-c1cc(-c2cccc(-c3ccccc3C#N)n2)cc(-n2c3ccccc3c3ccccc32)n1 ; N#Cc1cccc(-c2cccc(-c3cc(-n4c5ccccc5c5ccccc54)nc(-n4c5ccccc5c5cc(C#N)ccc54)c3)n2)c1]

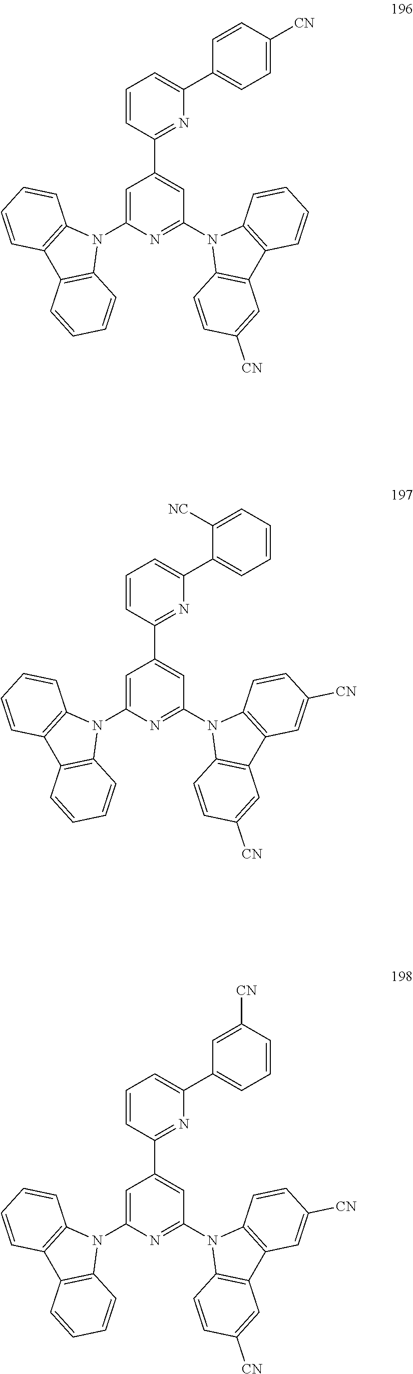 [SMILES: N#Cc1ccc(-c2cccc(-c3cc(-n4c5ccccc5c5ccccc54)nc(-n4c5ccccc5c5cc(C#N)ccc54)c3)n2)cc1 ; N#Cc1ccc2c(c1)c1cc(C#N)ccc1n2-c1cc(-c2cccc(-c3ccccc3C#N)n2)cc(-n2c3ccccc3c3ccccc32)n1 ; N#Cc1cccc(-c2cccc(-c3cc(-n4c5ccccc5c5ccccc54)nc(-n4c5ccc(C#N)cc5c5cc(C#N)ccc54)c3)n2)c1]

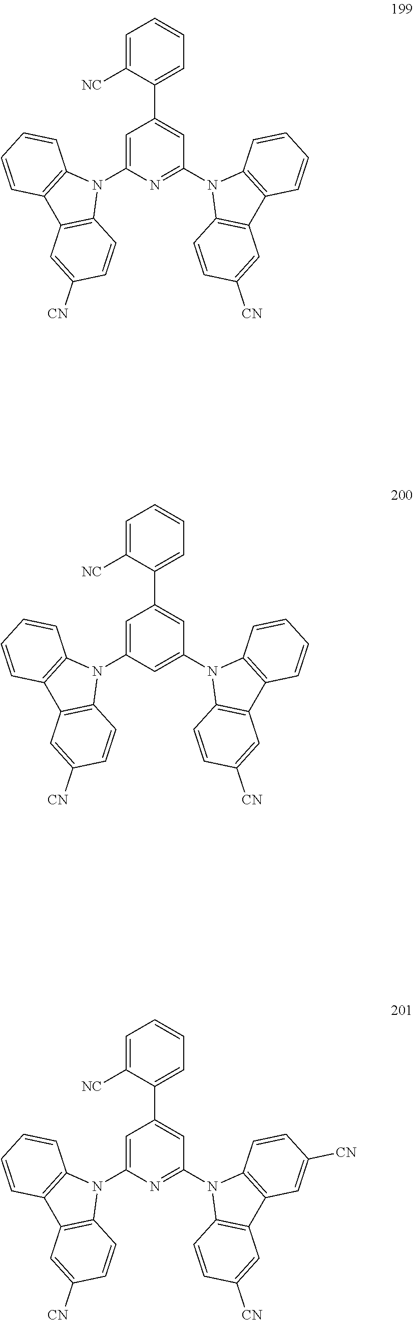

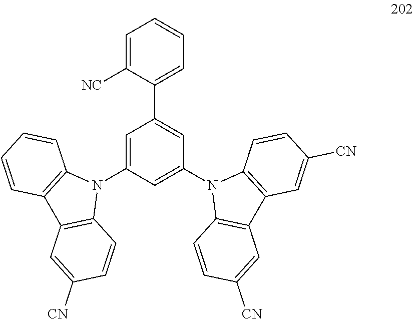

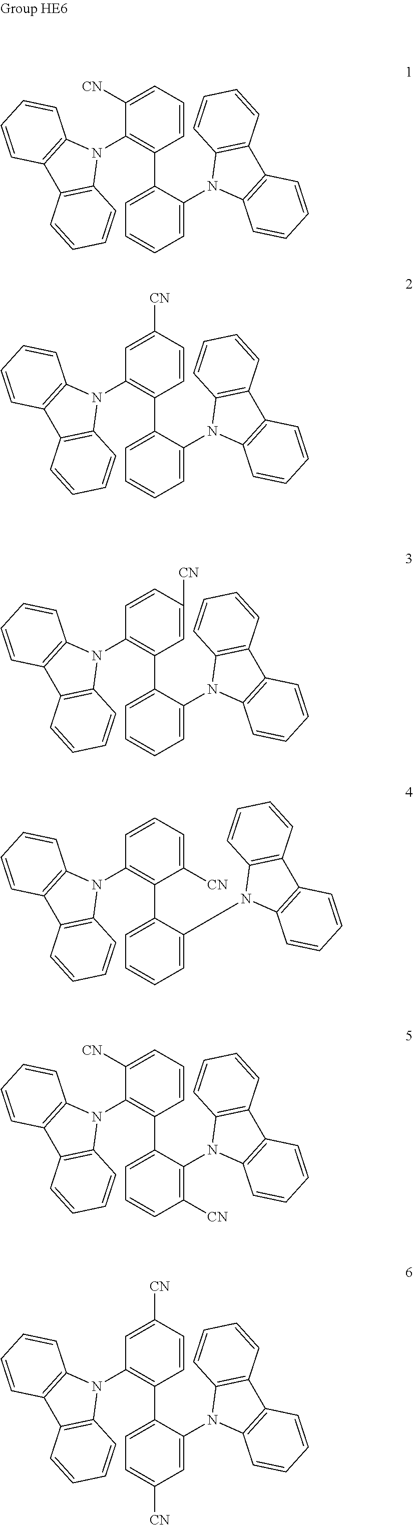

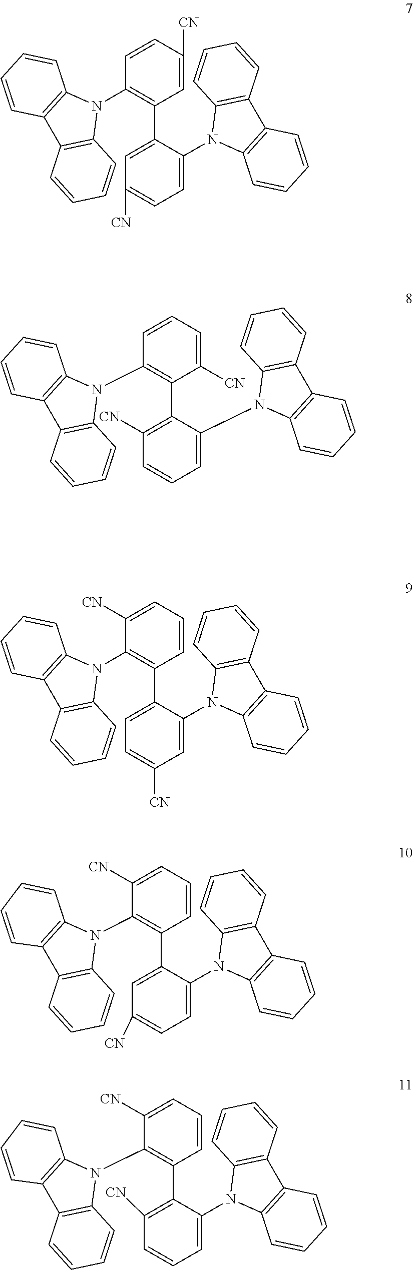

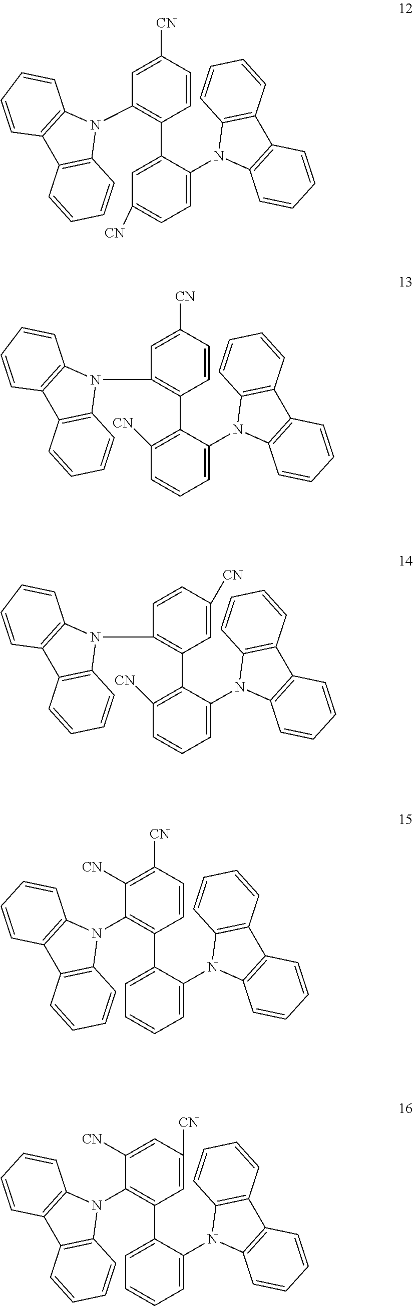

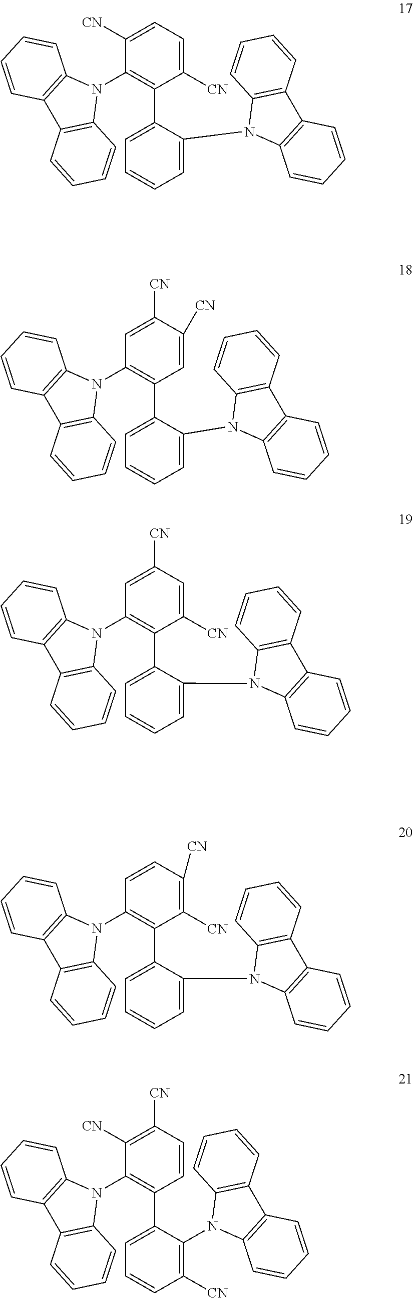

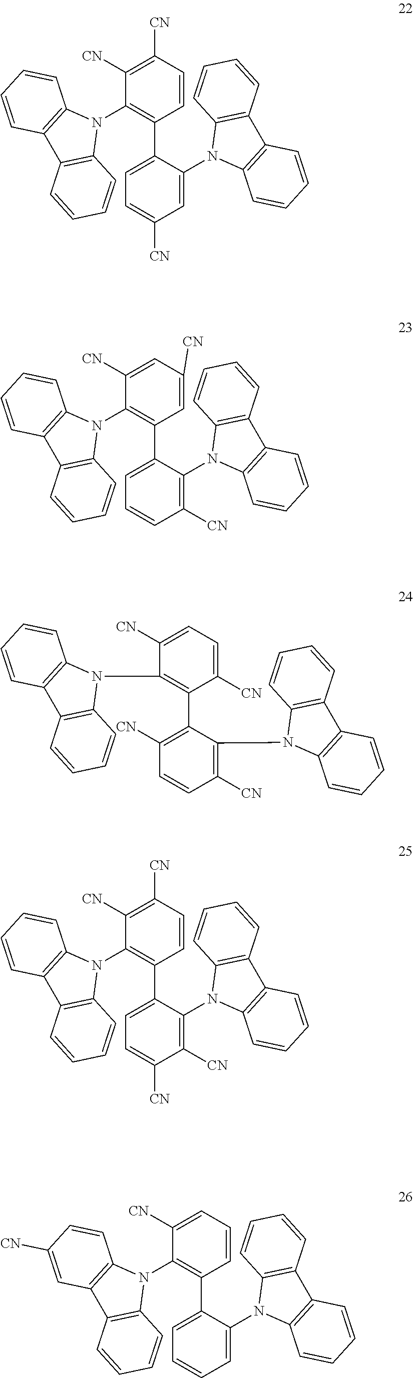

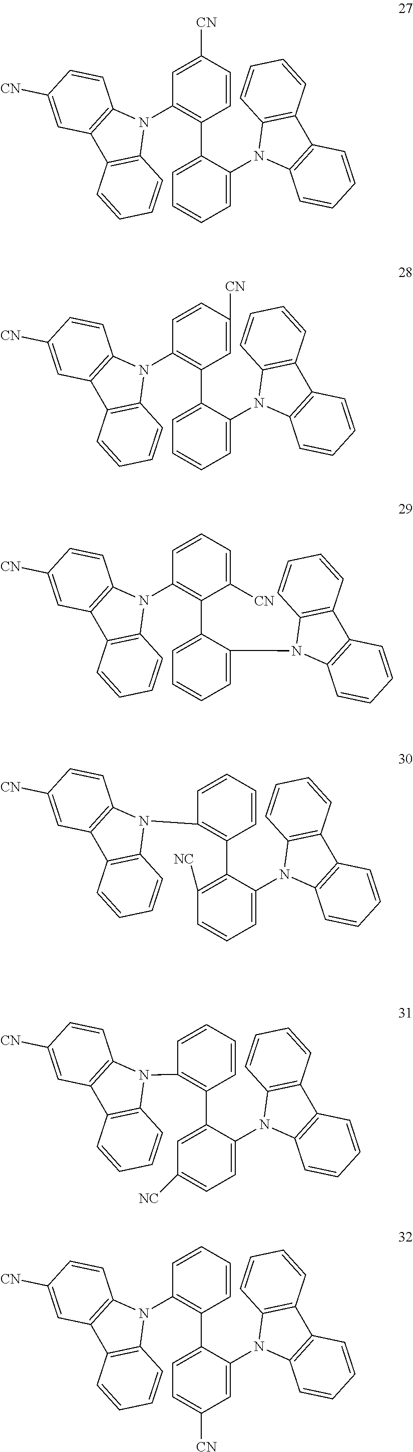

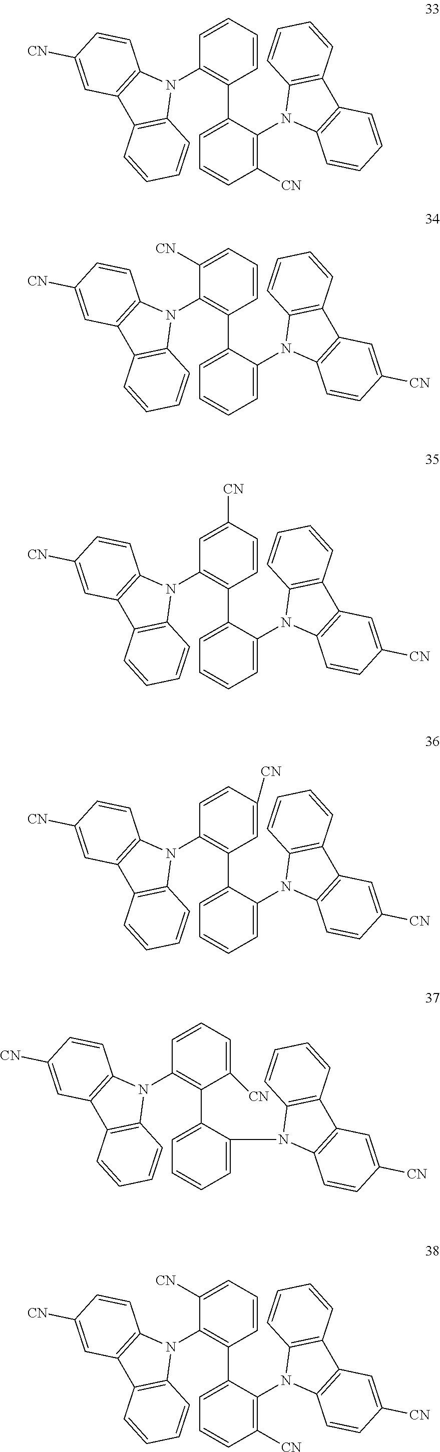

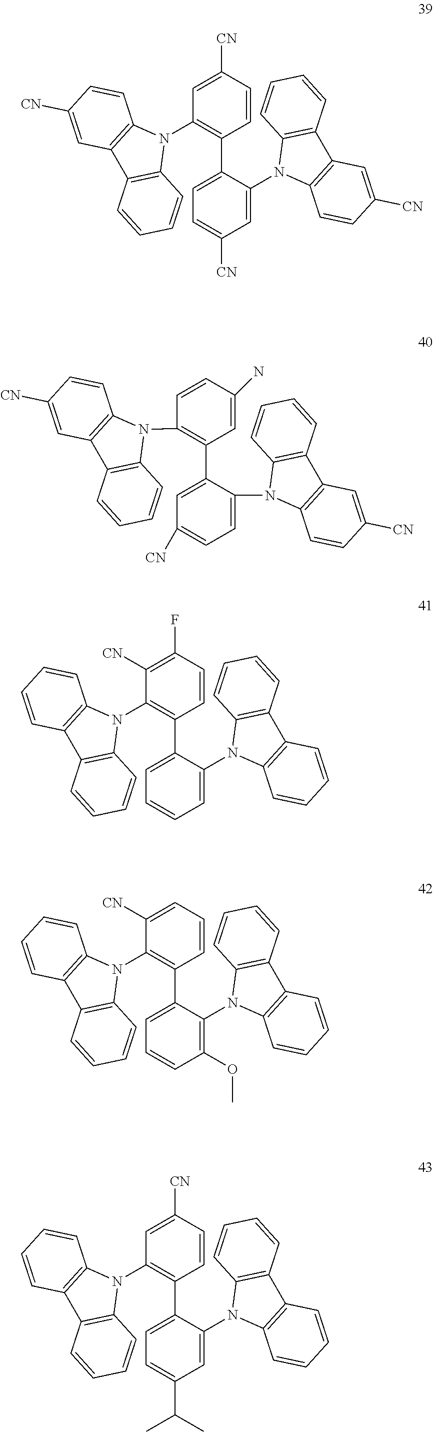

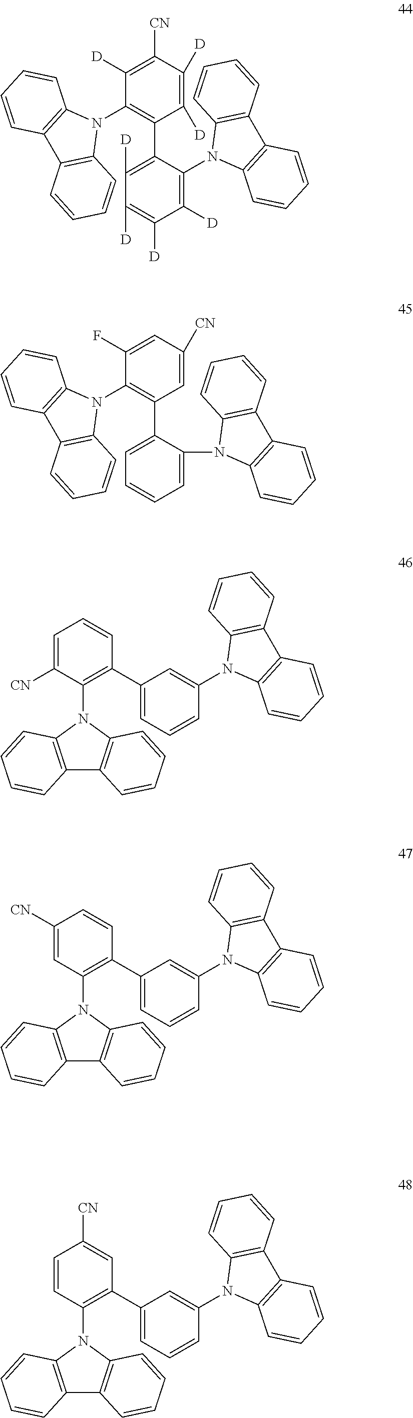

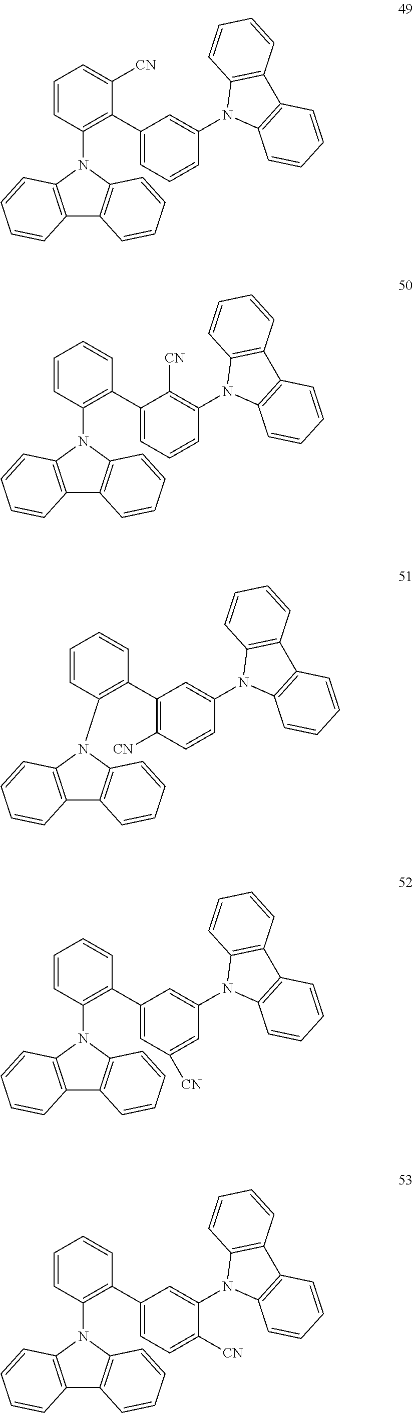

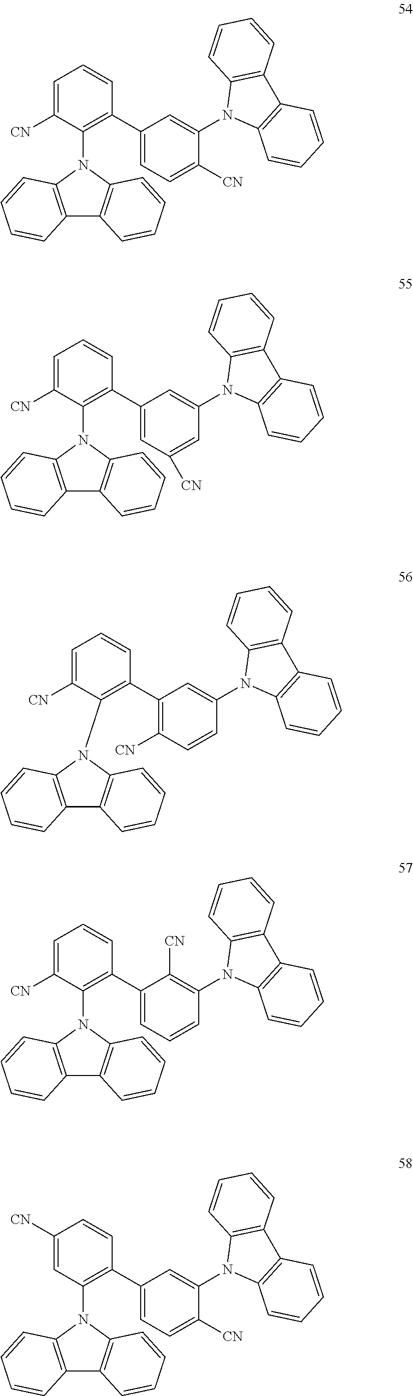

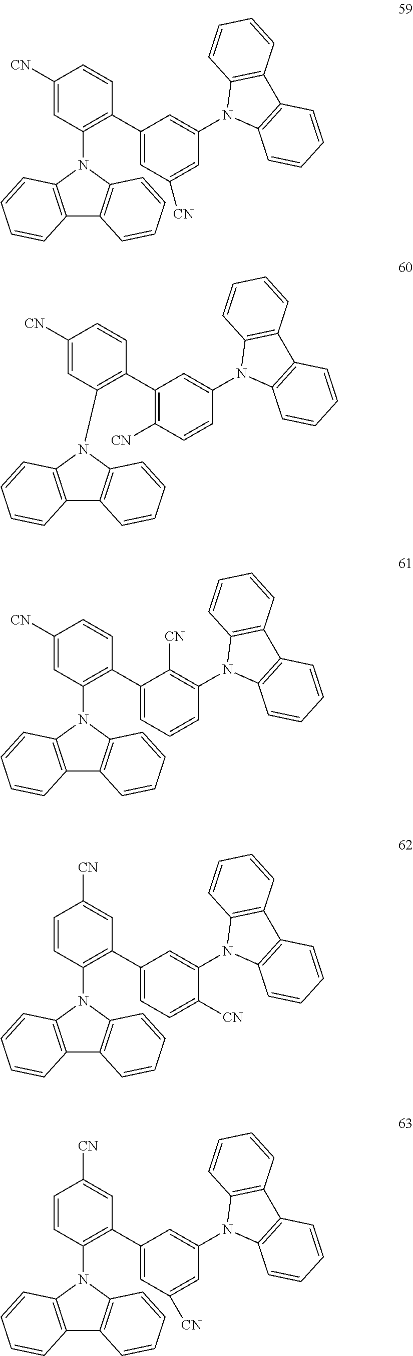

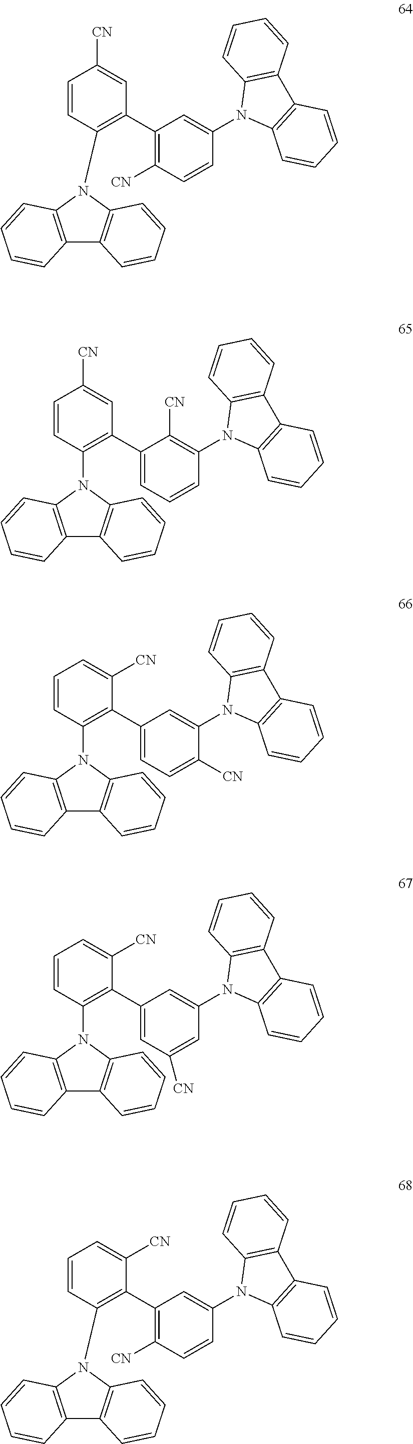

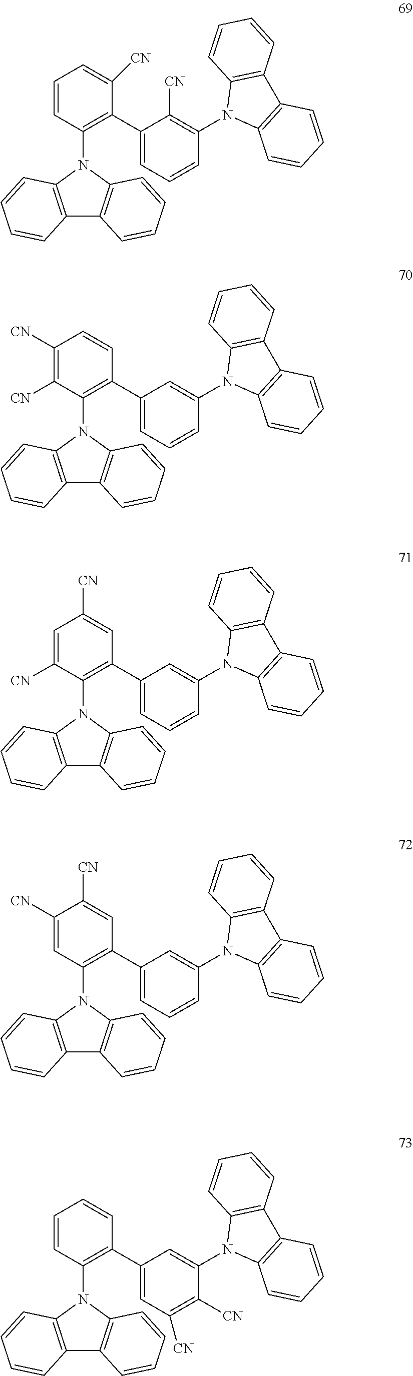

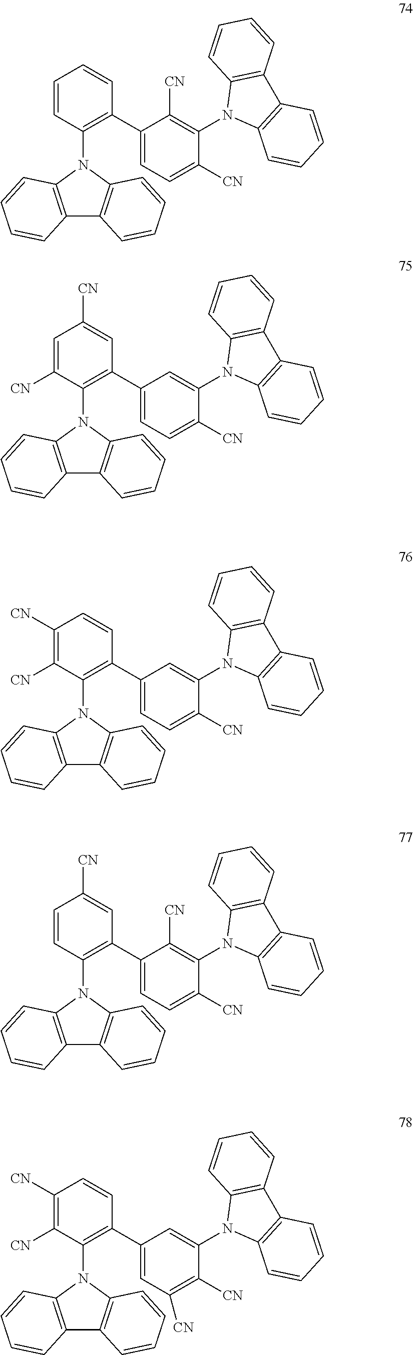

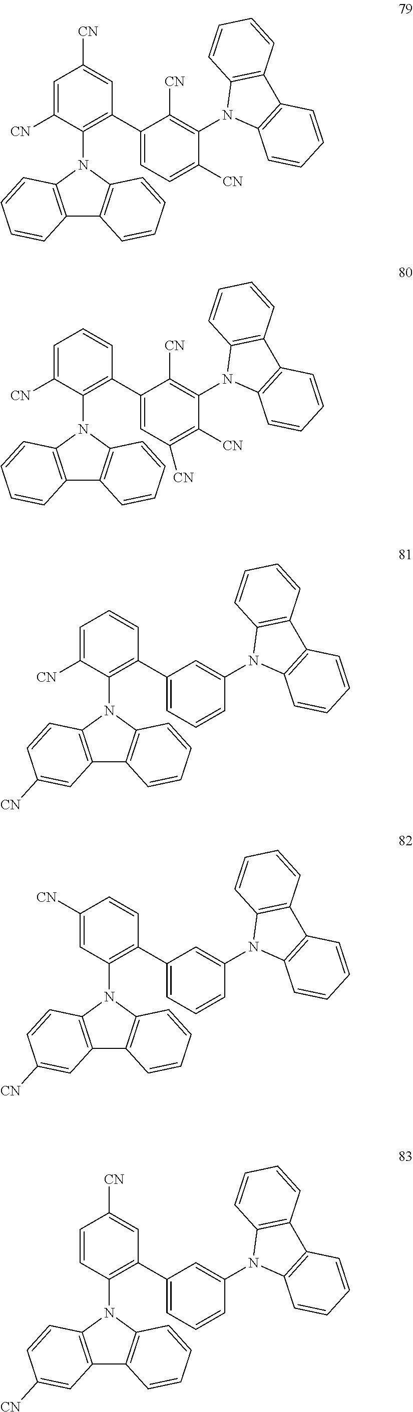

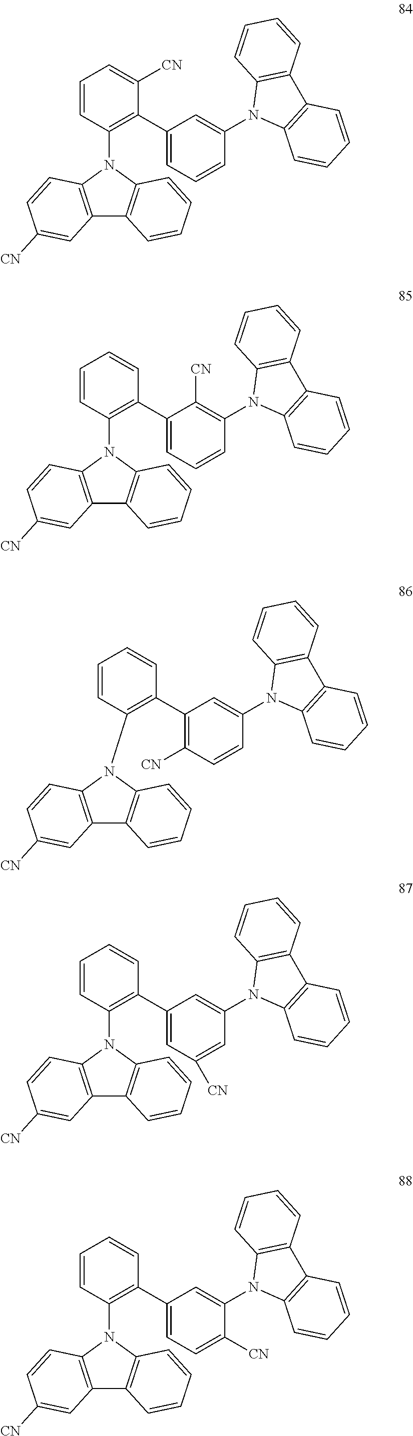

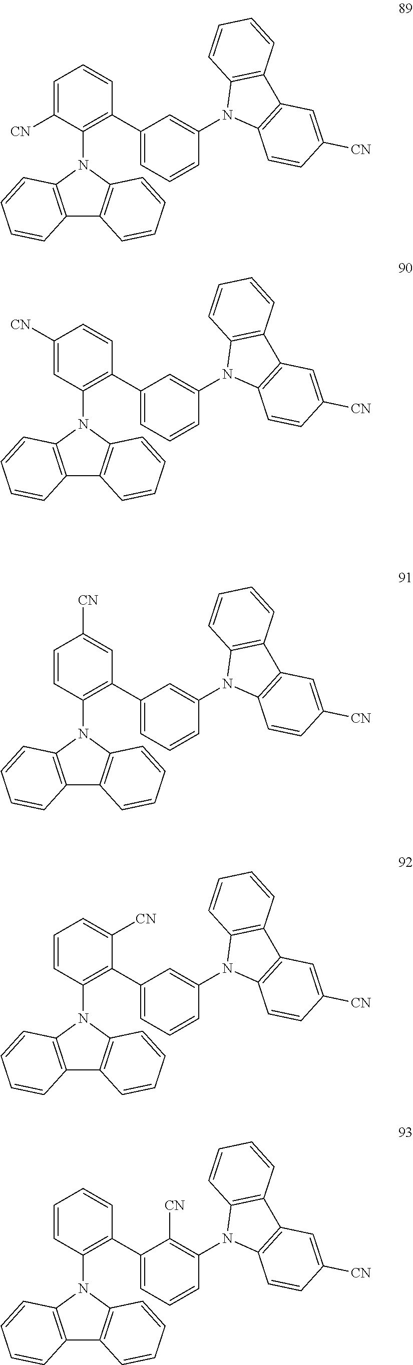

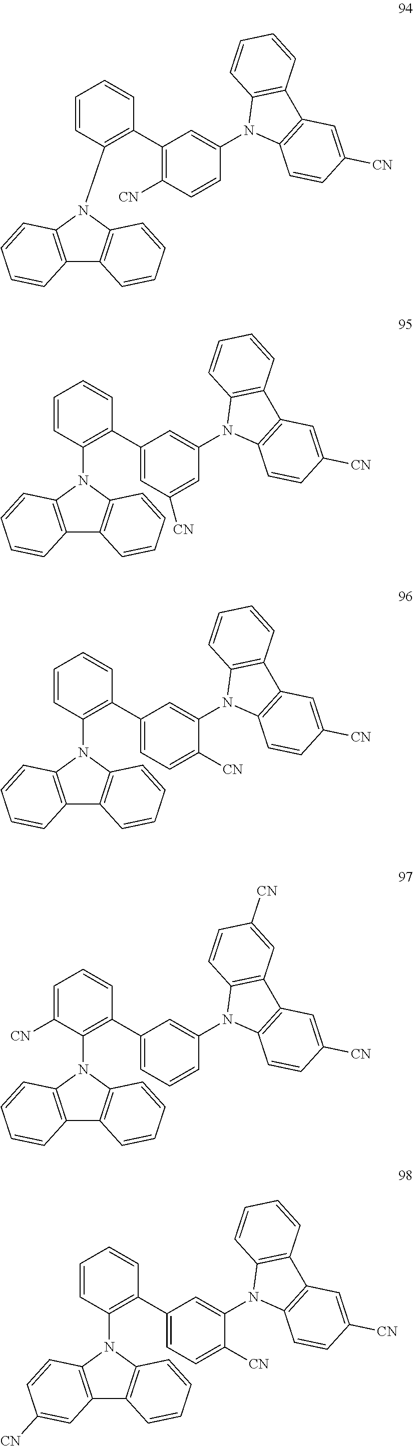

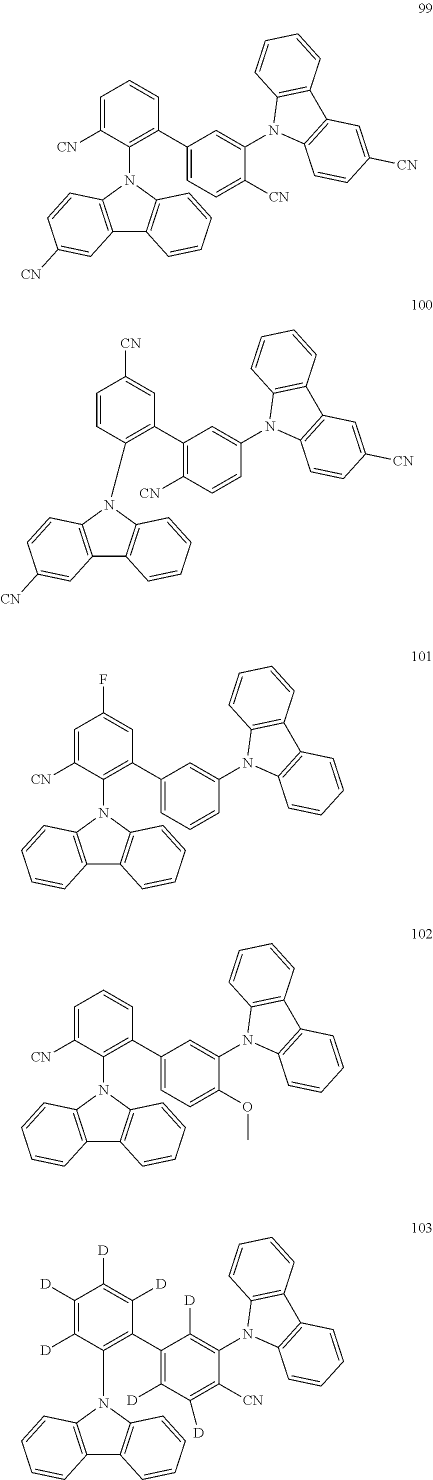

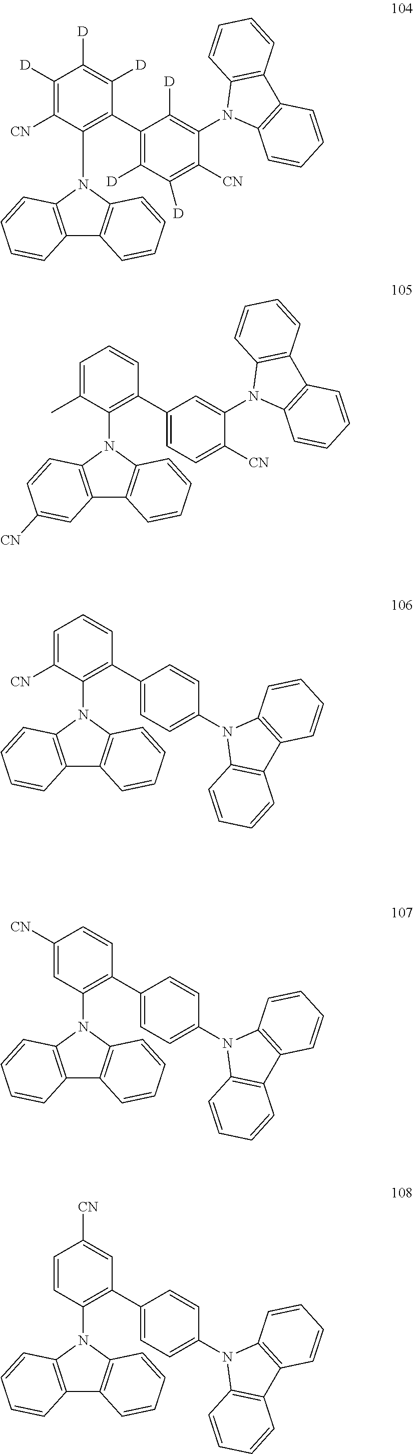

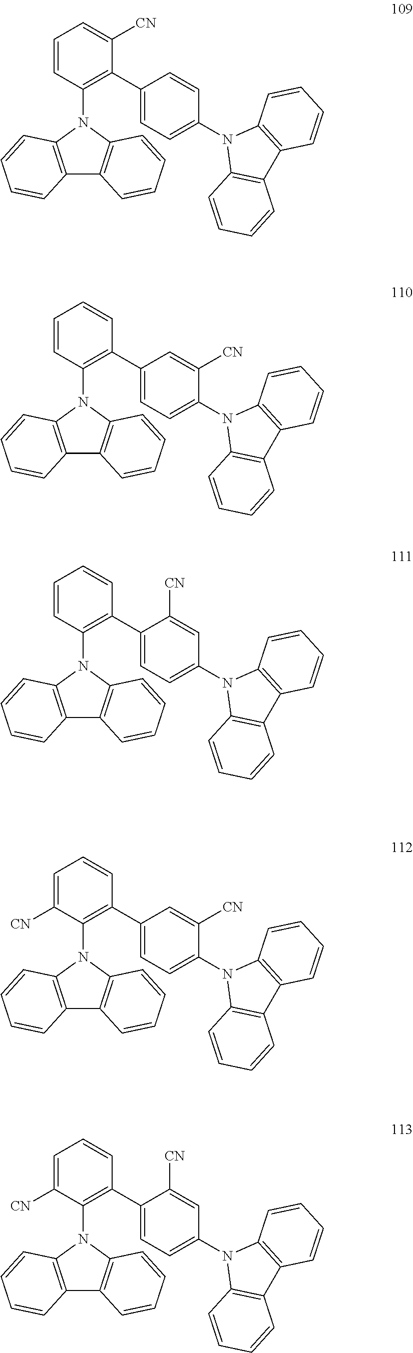

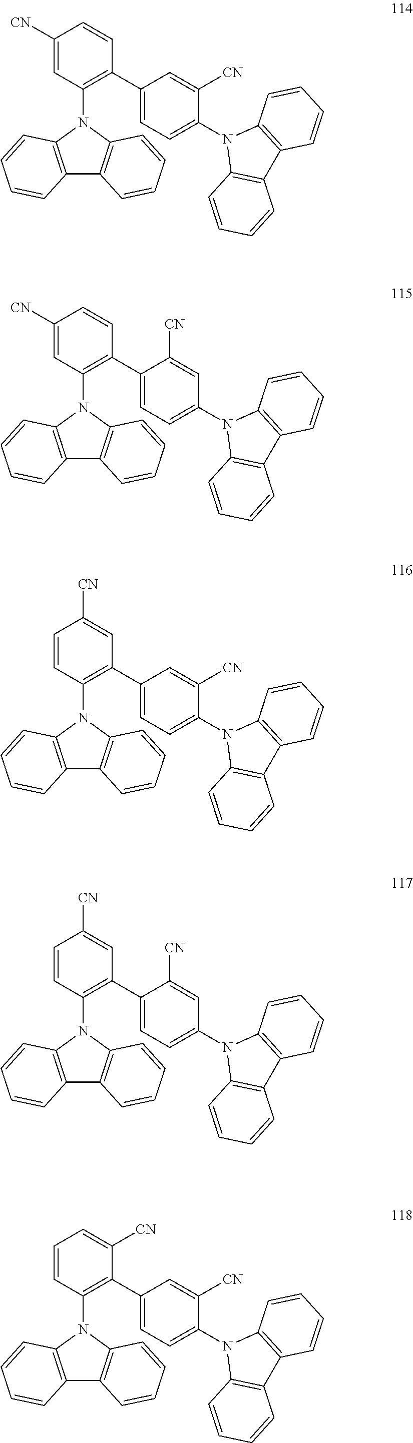

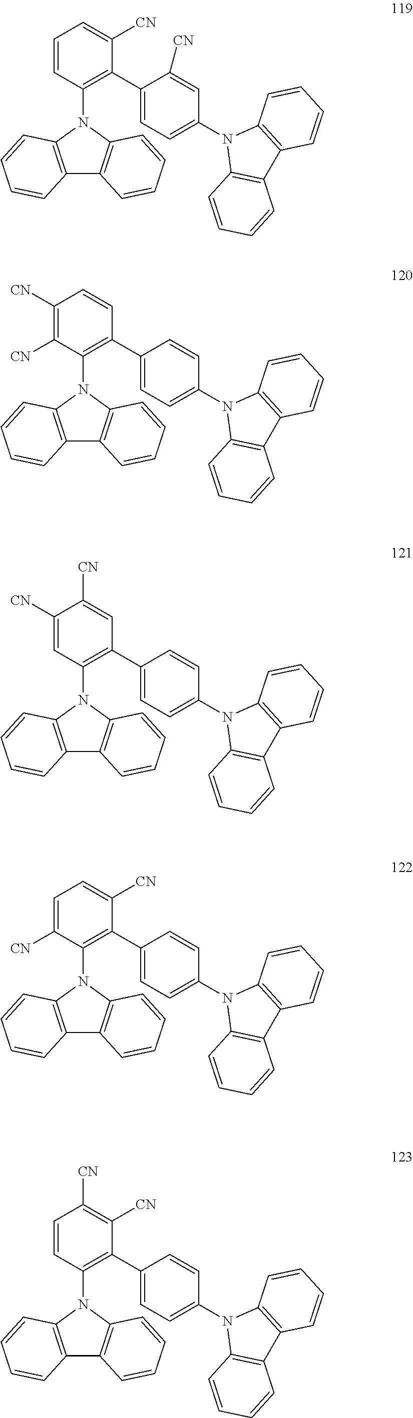

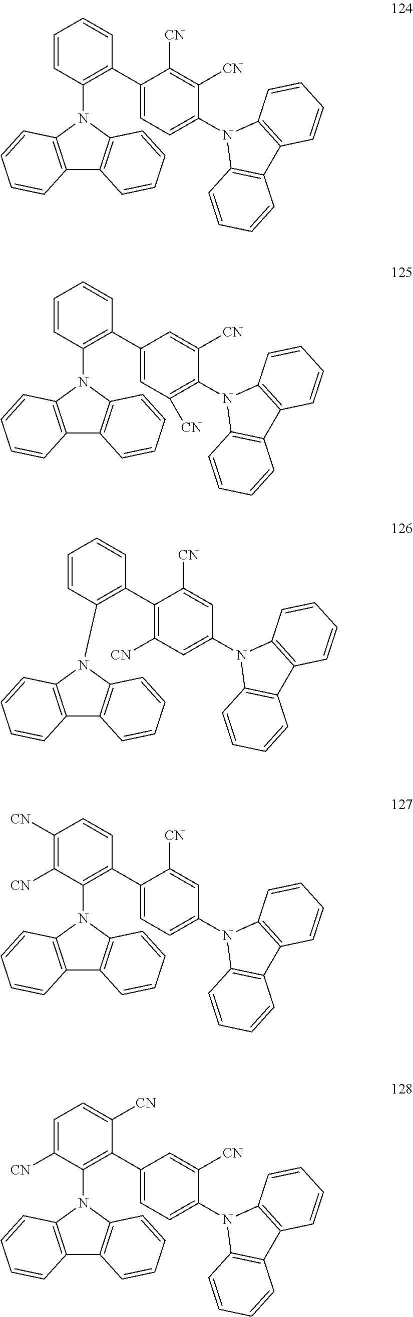

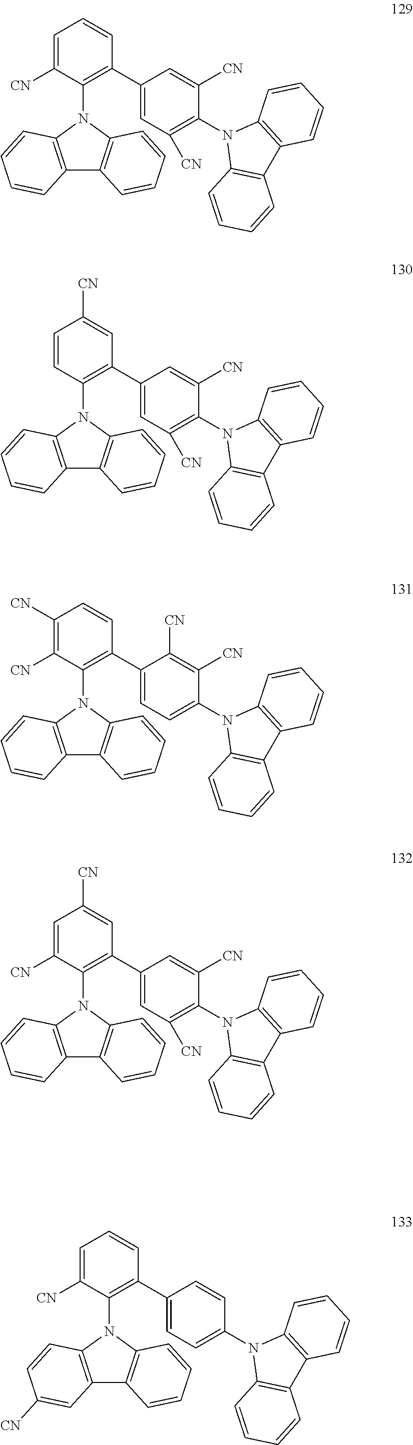

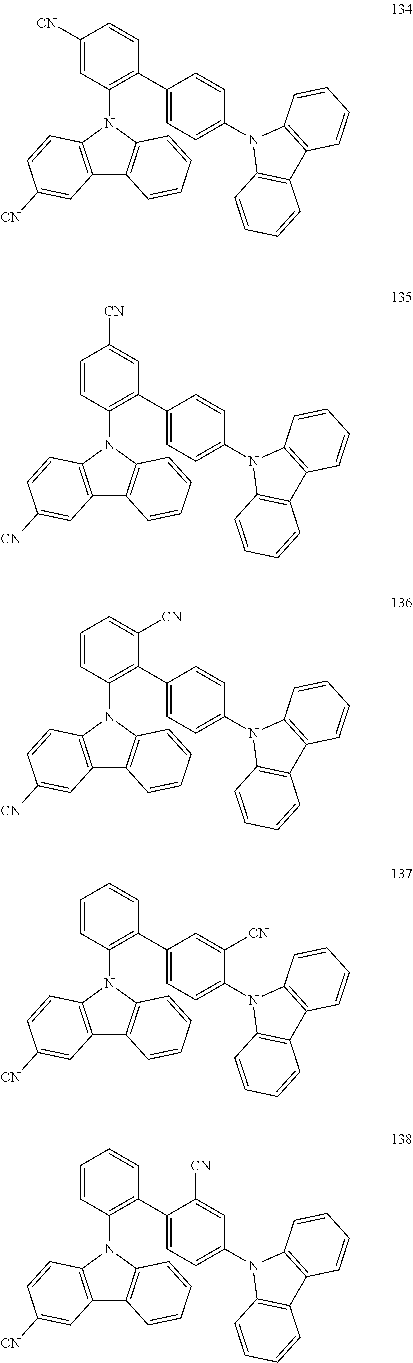

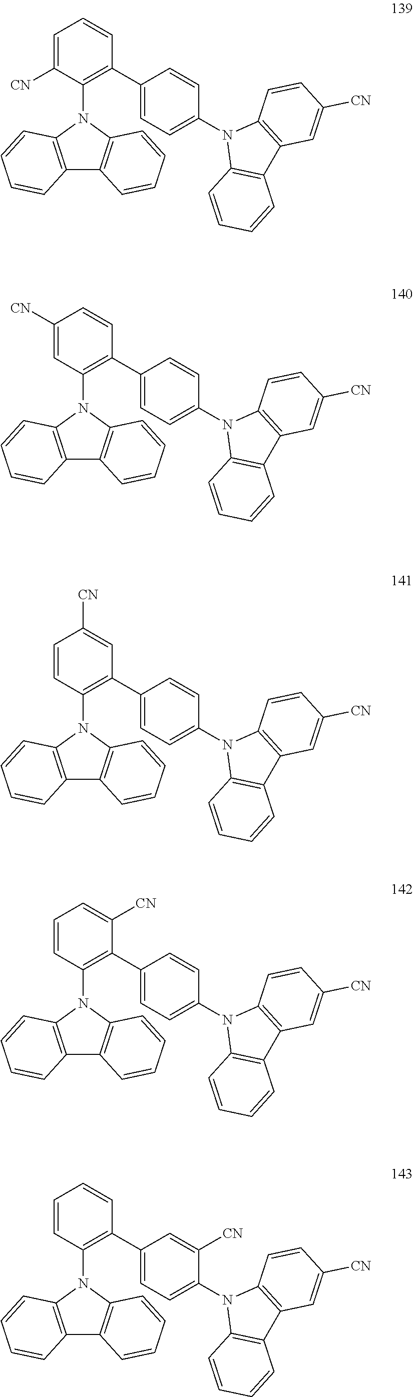

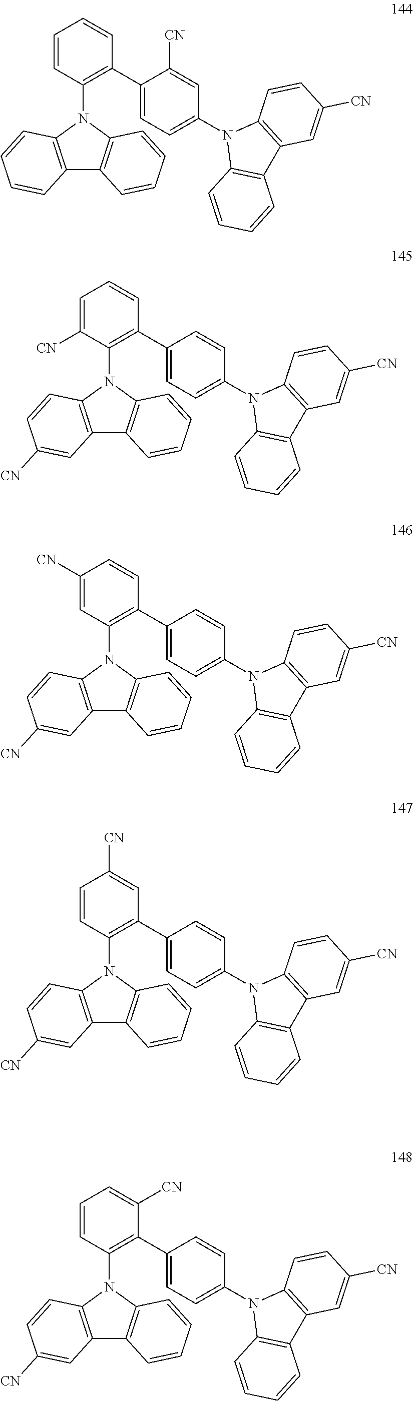

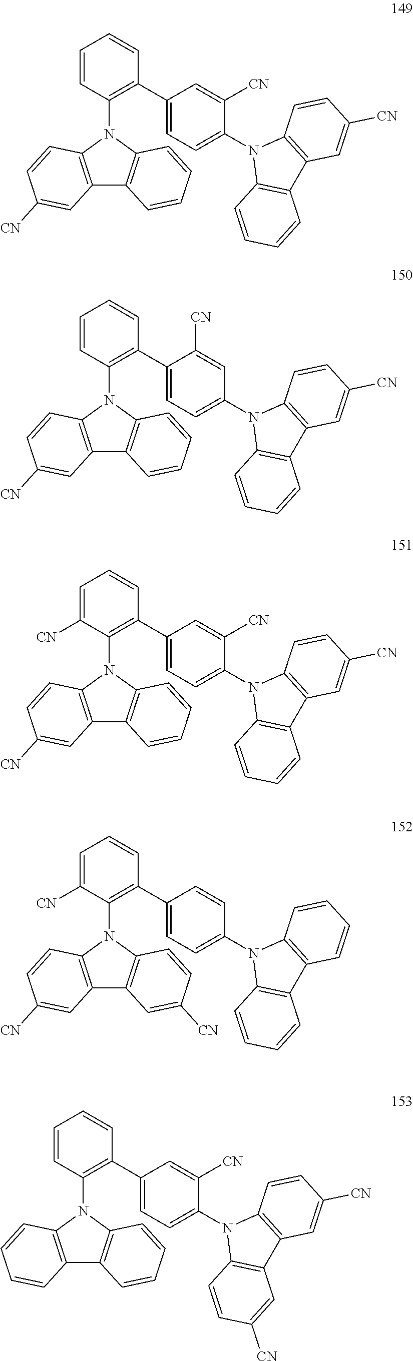

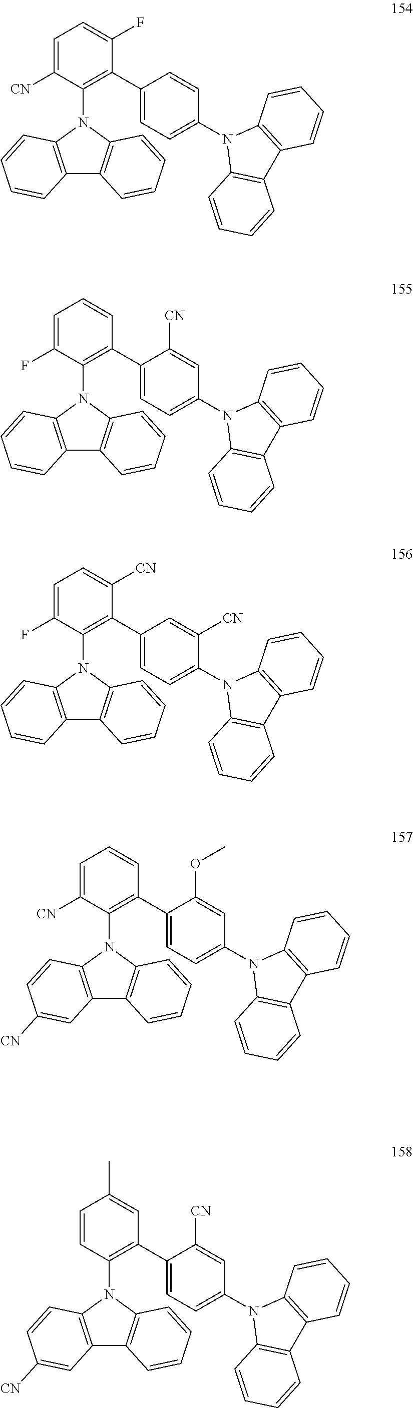

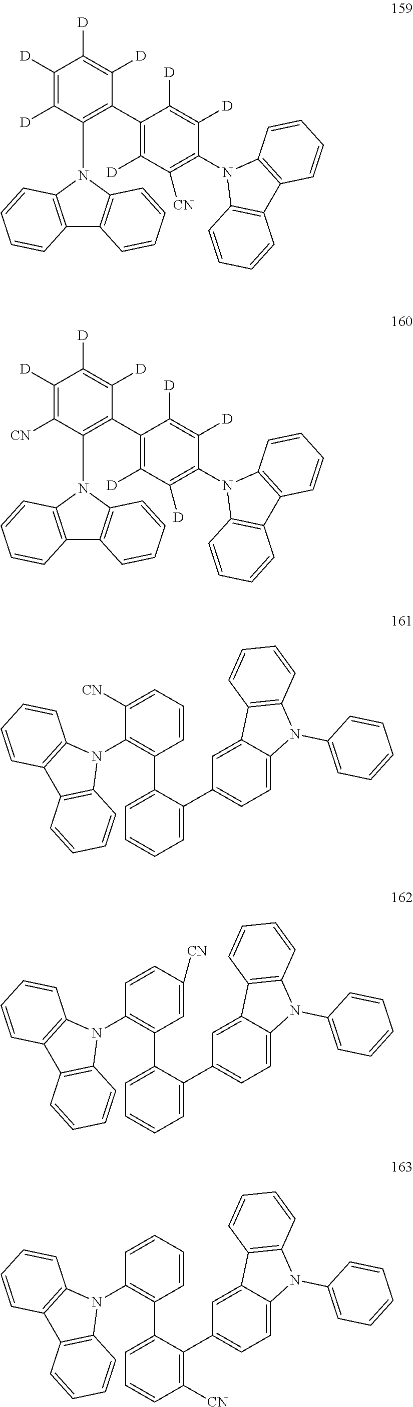

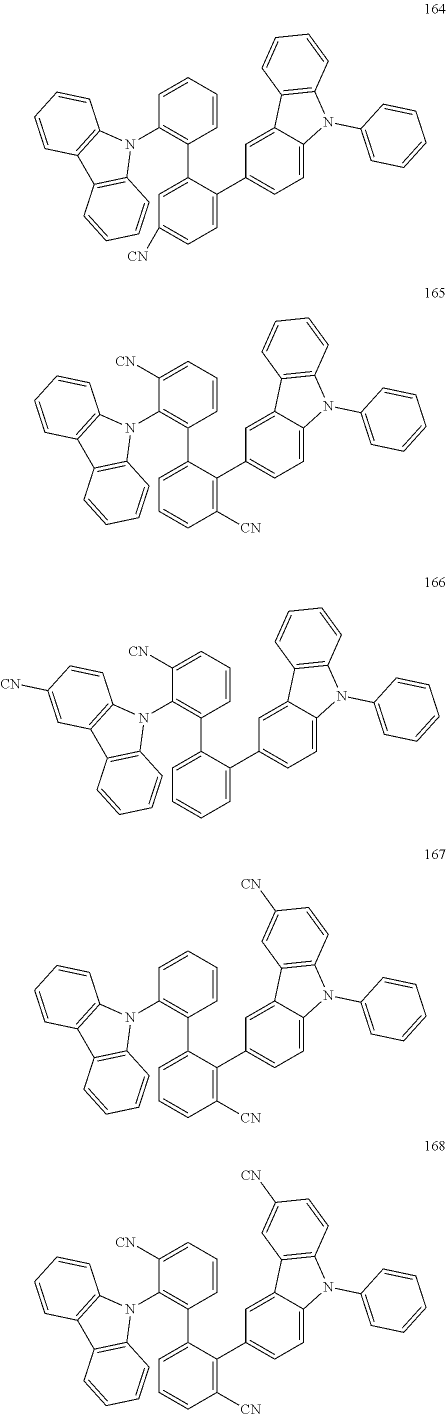

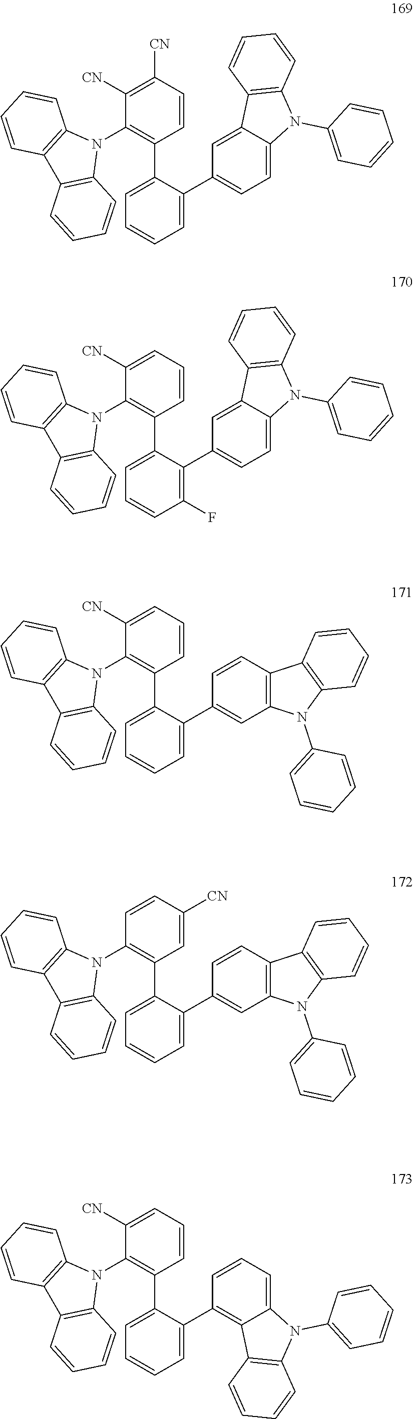

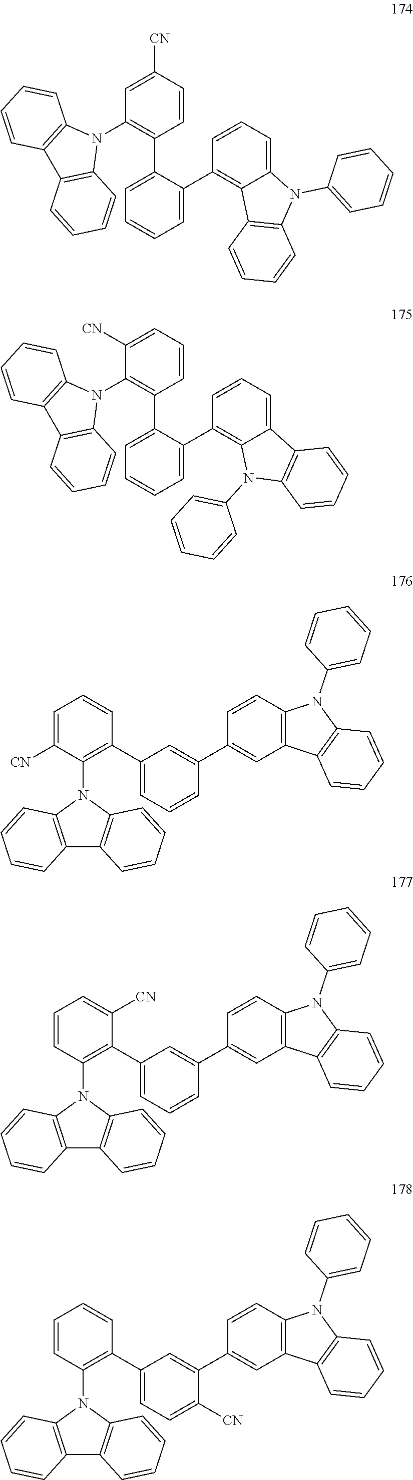

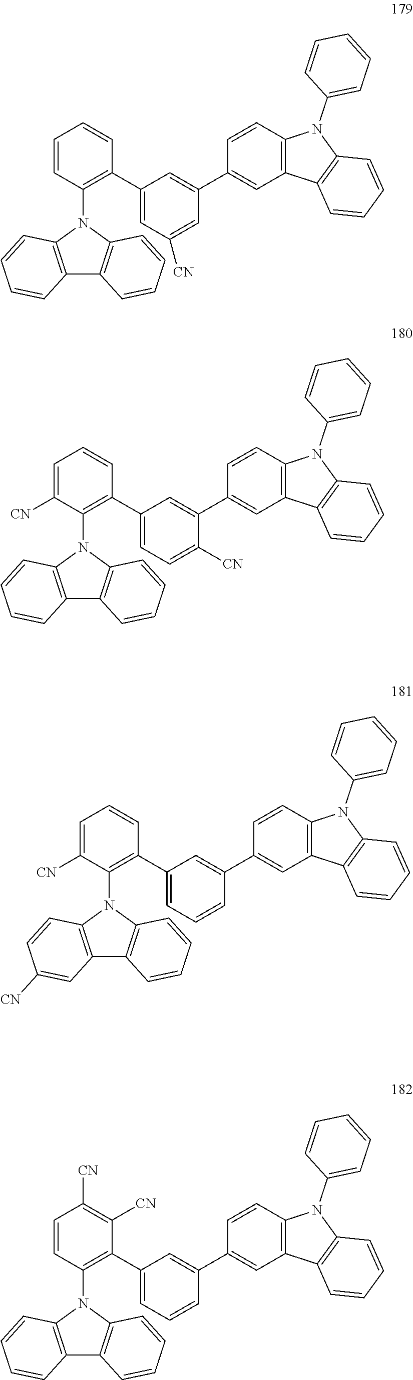

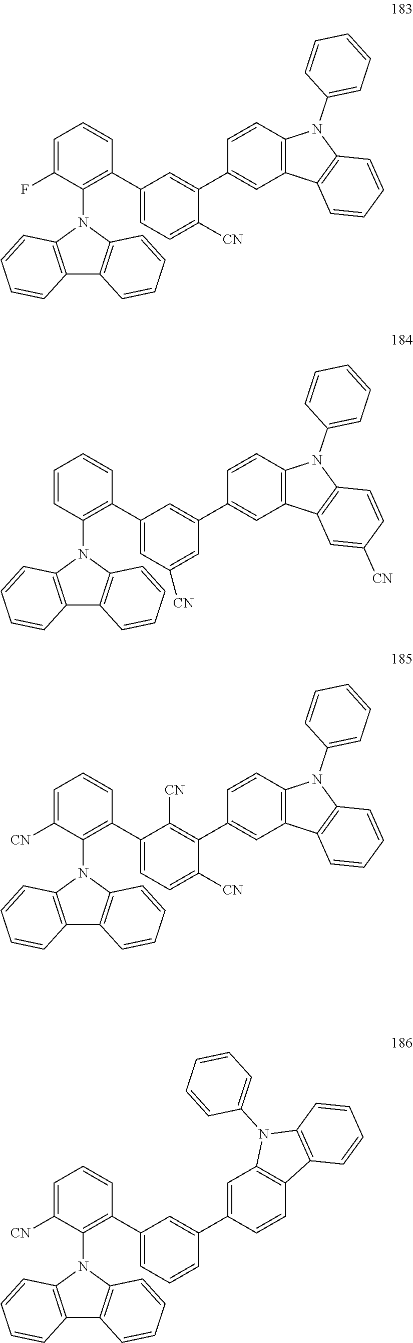

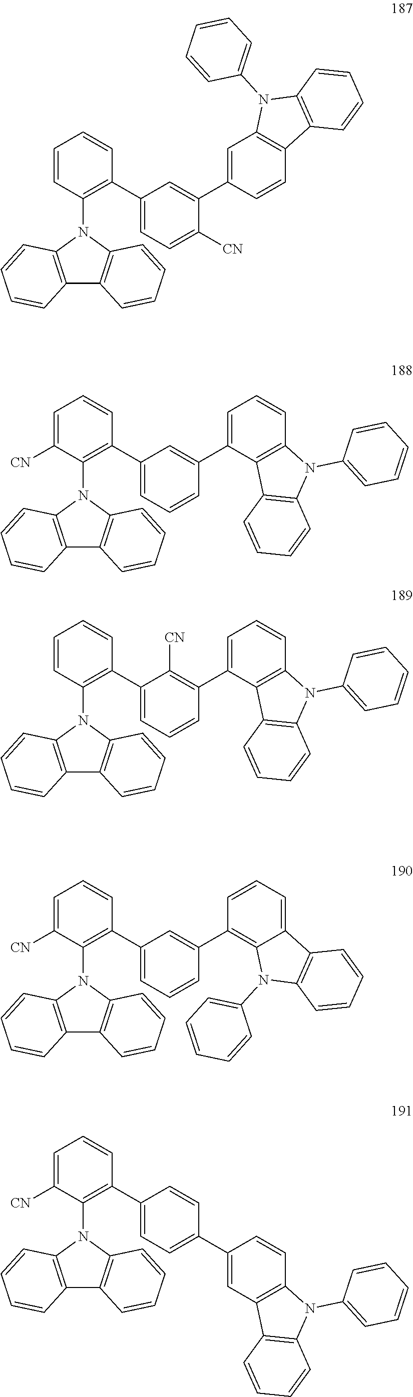

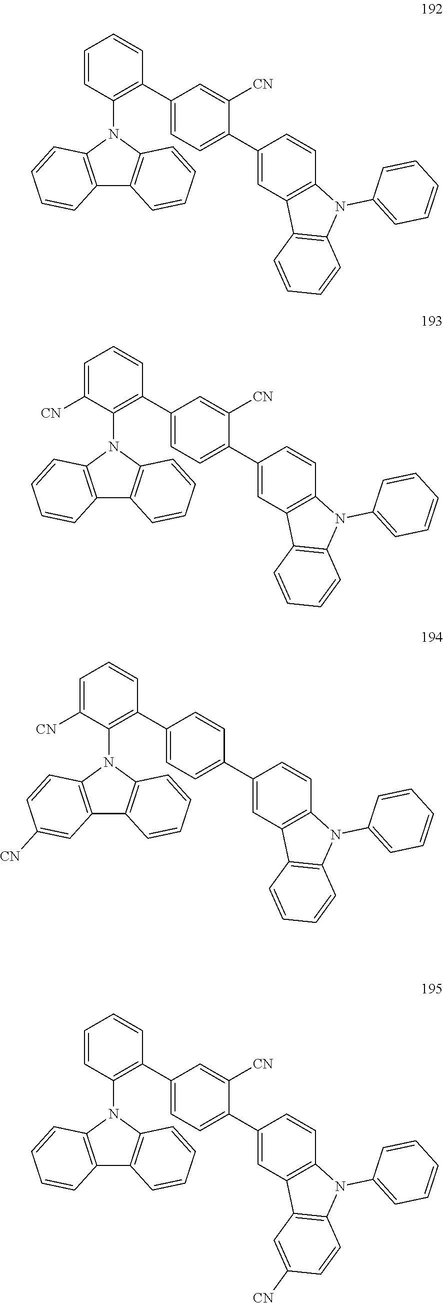

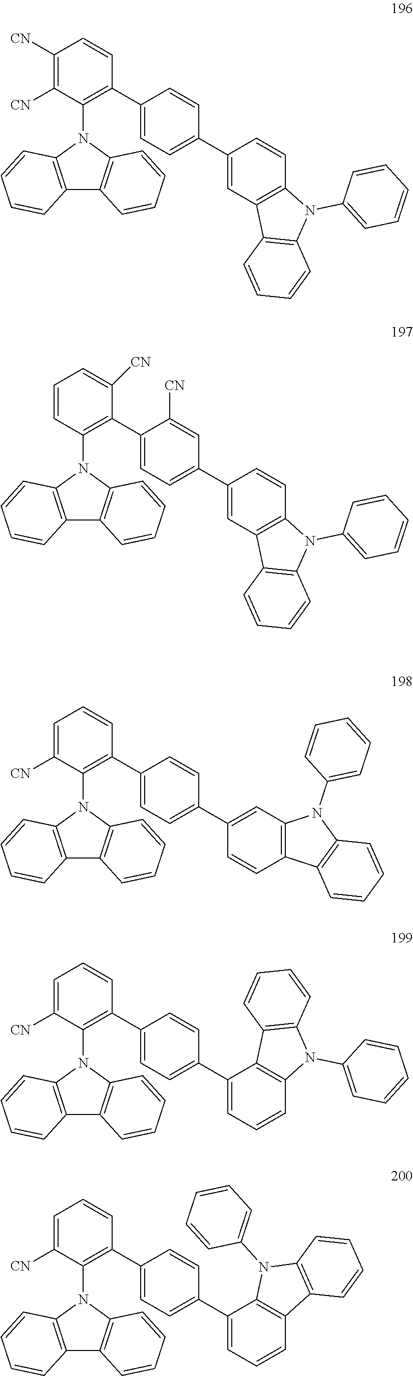

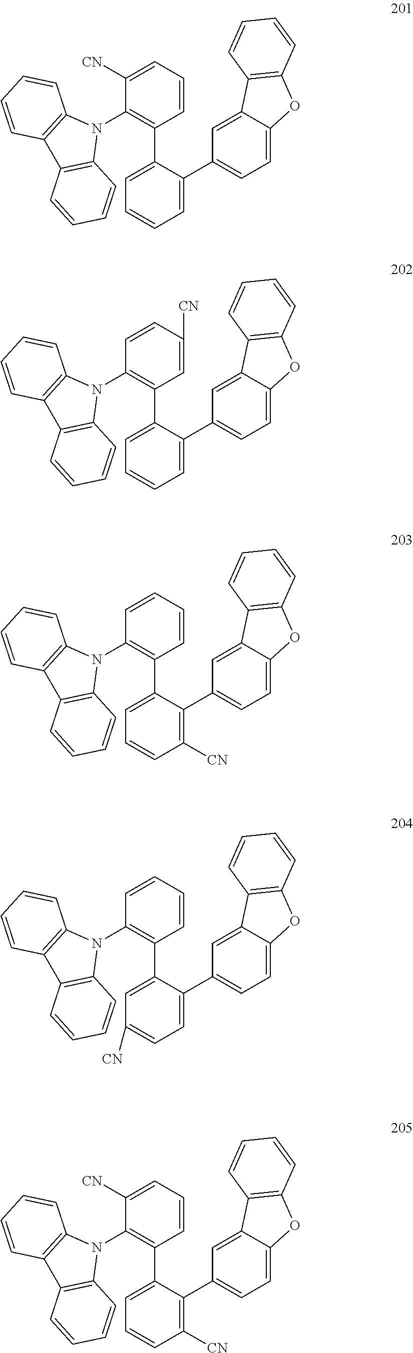

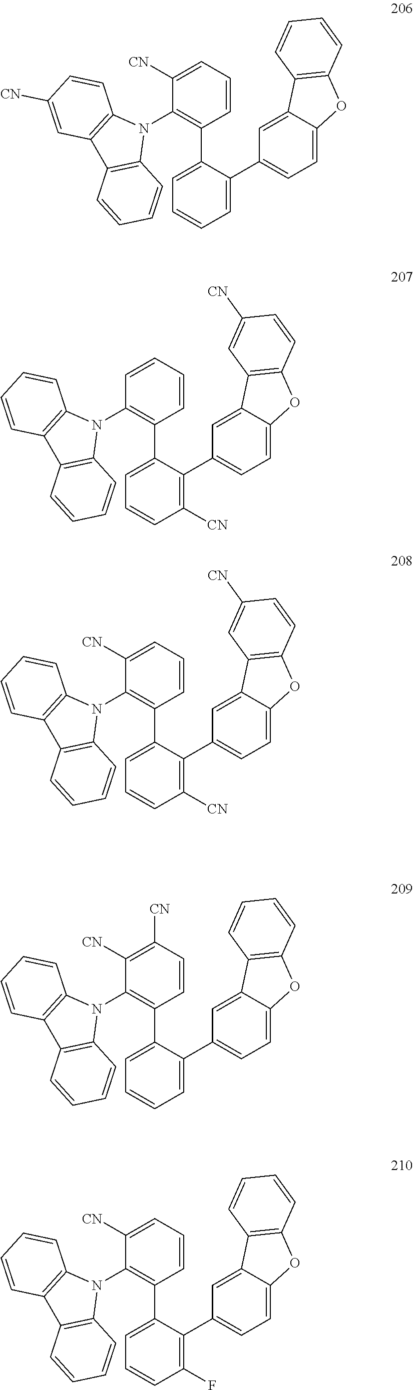

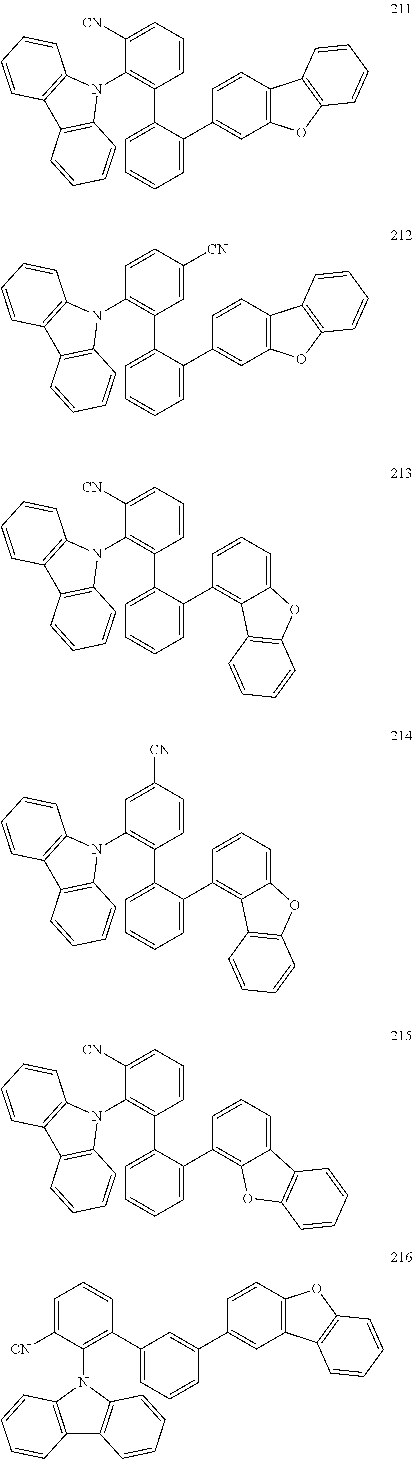

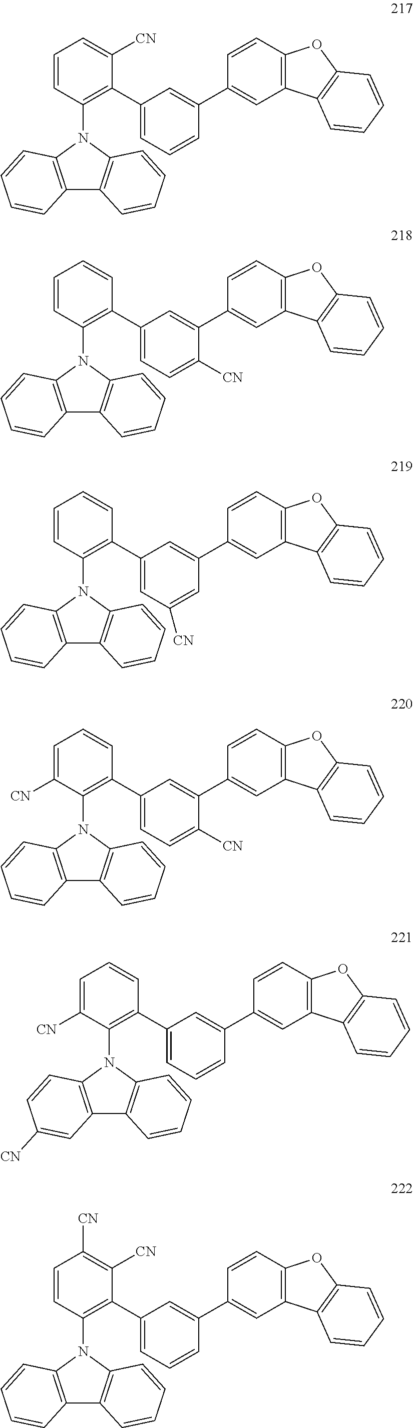

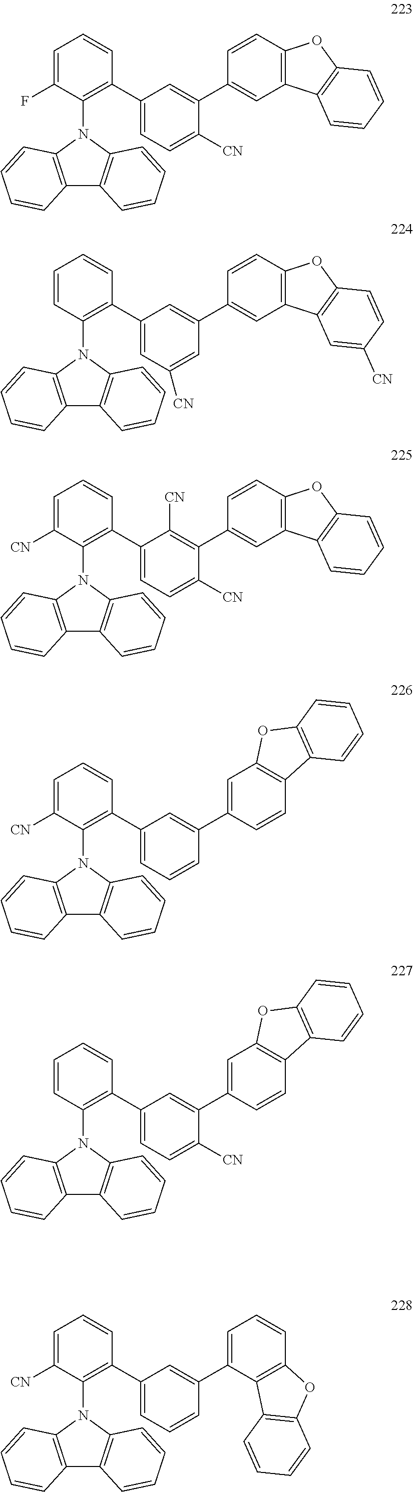

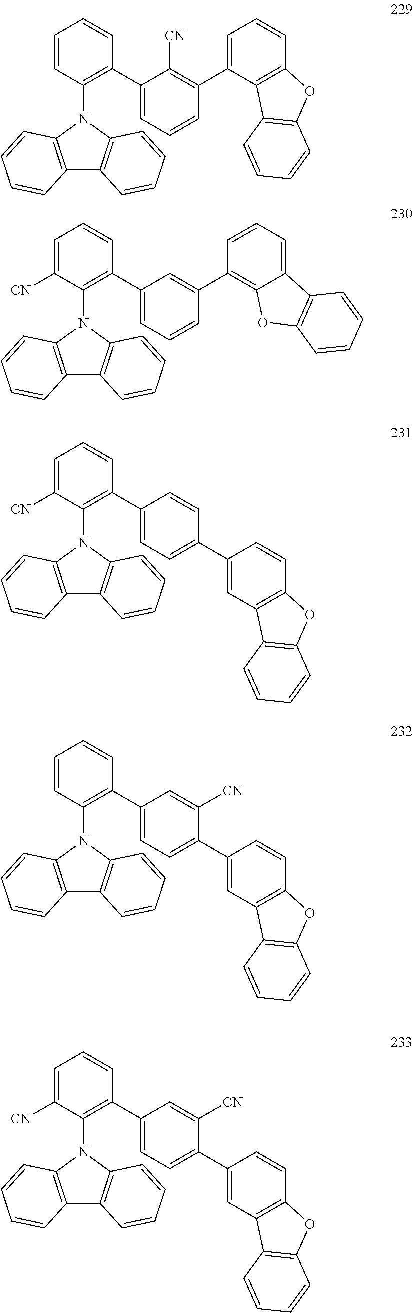

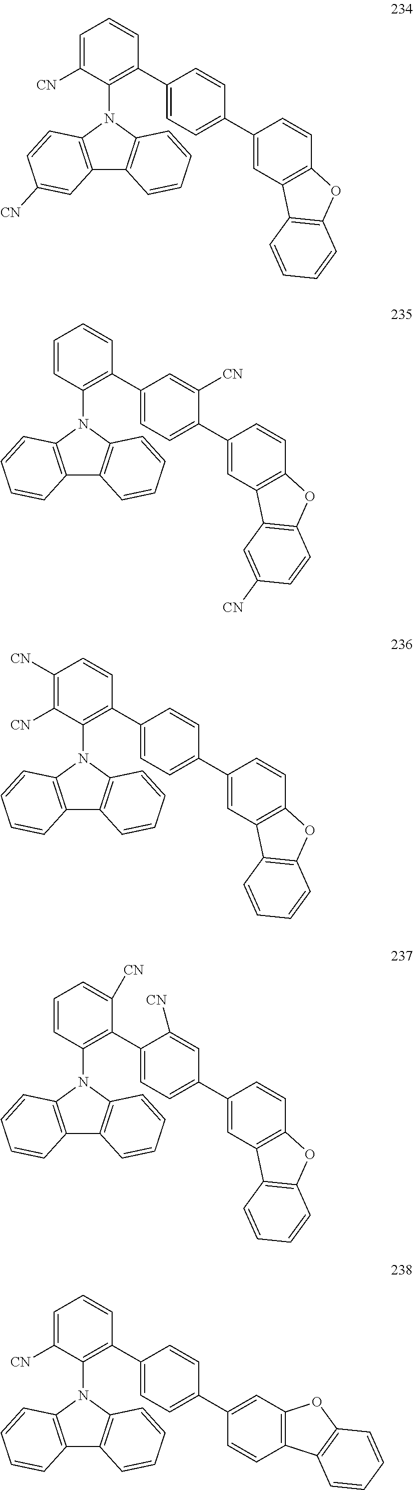

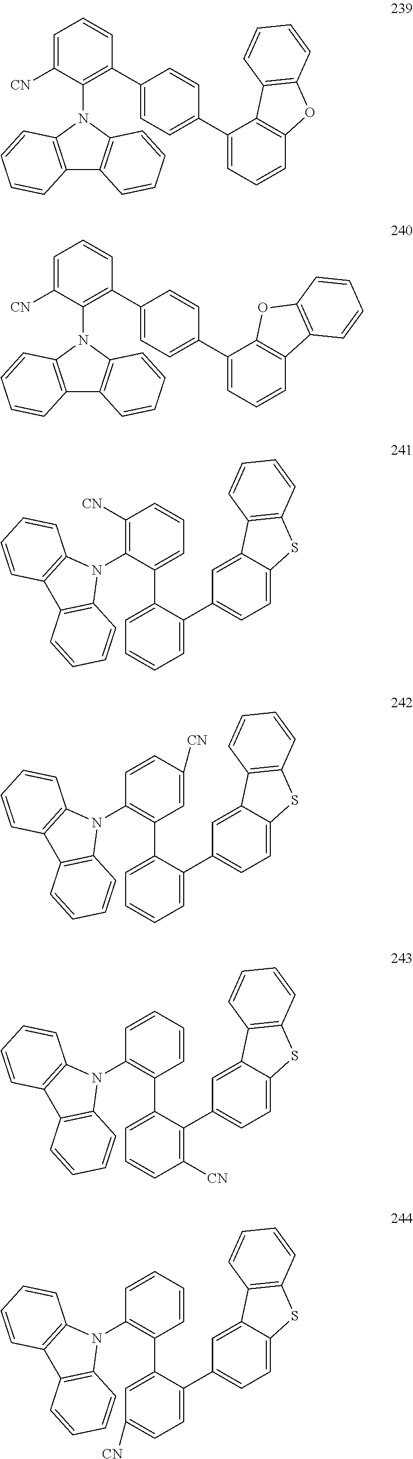

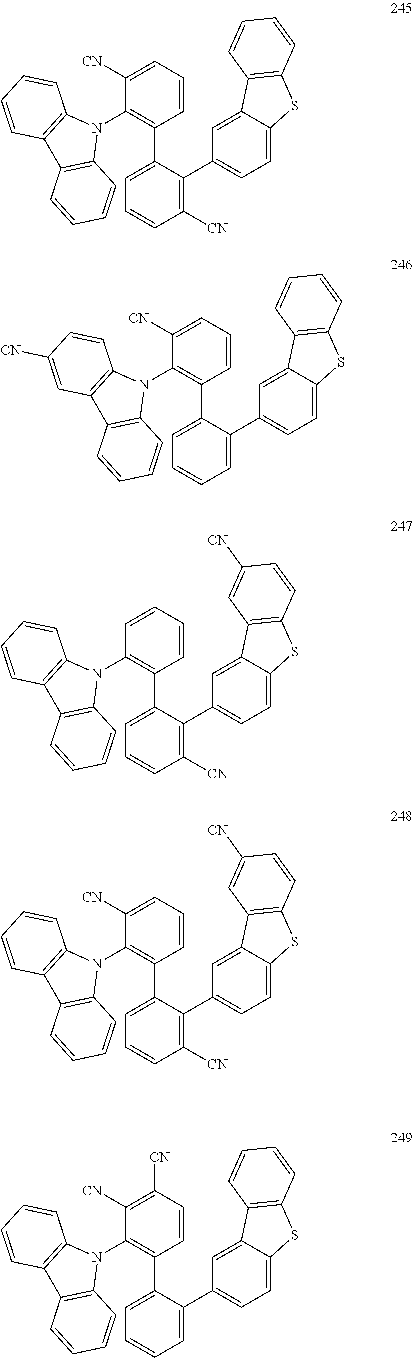

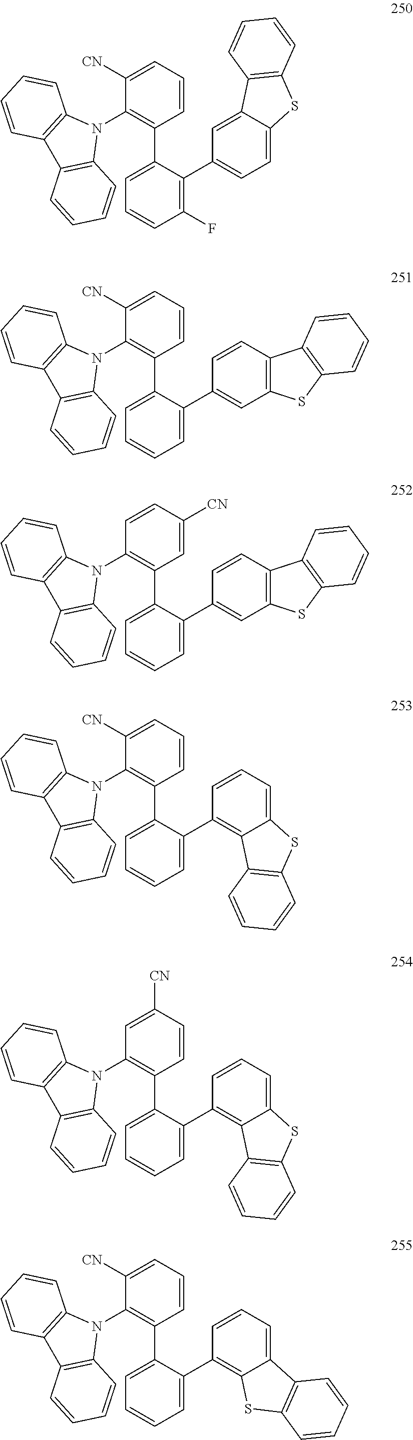

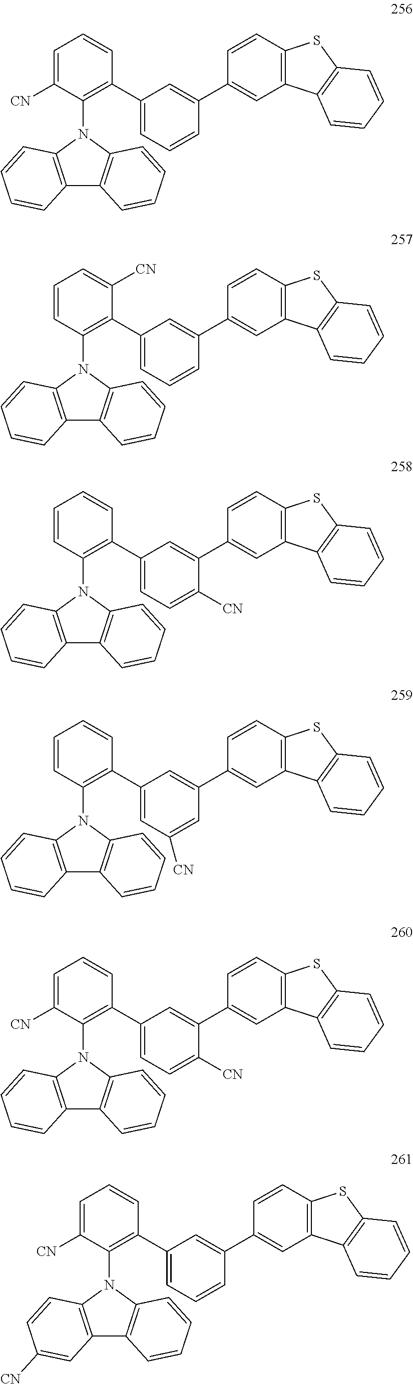

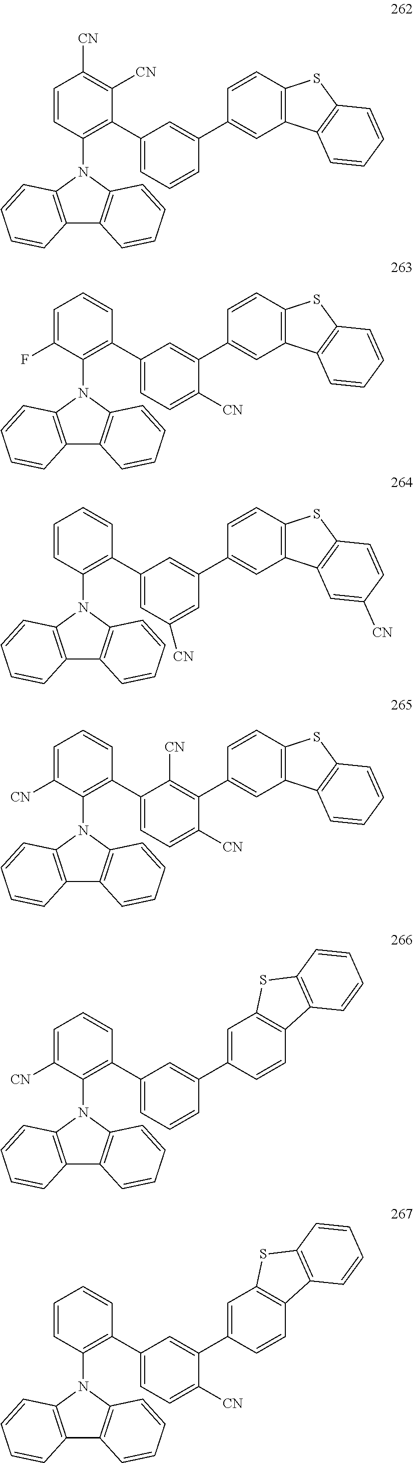

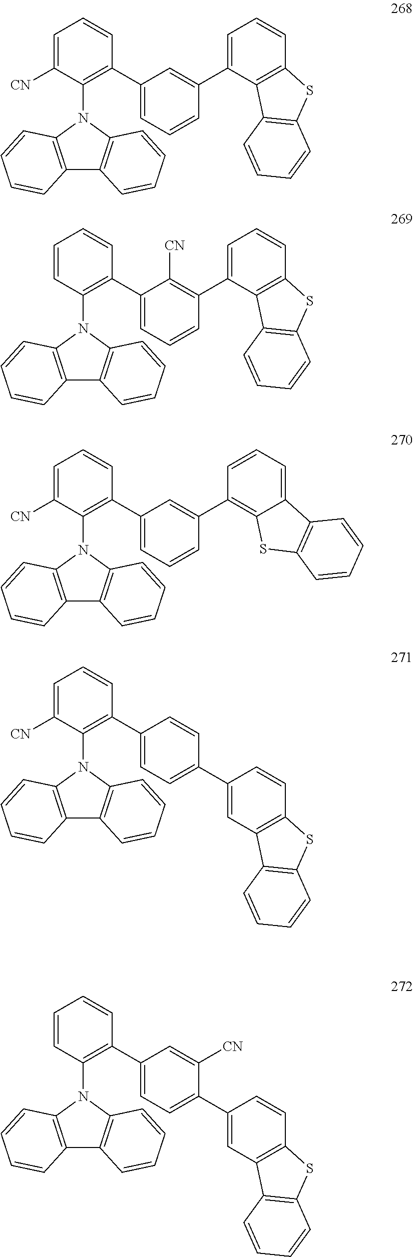

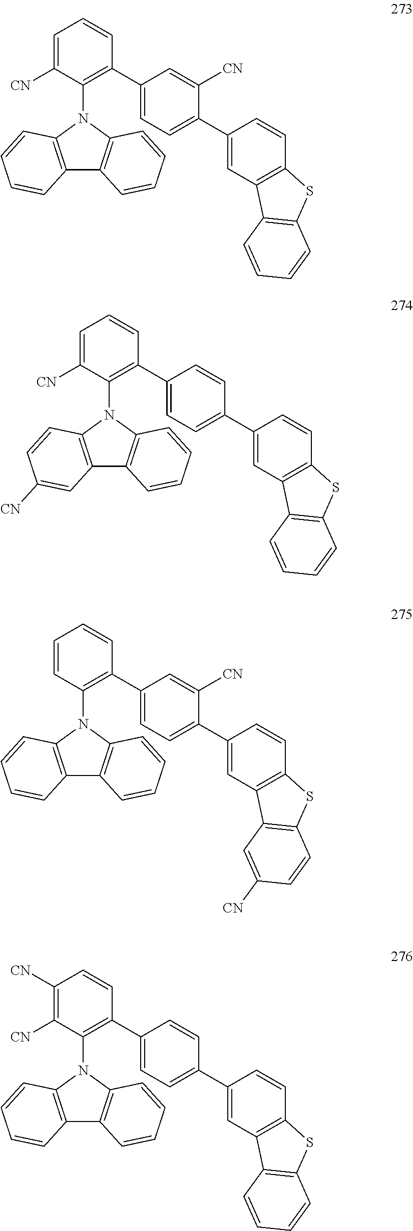

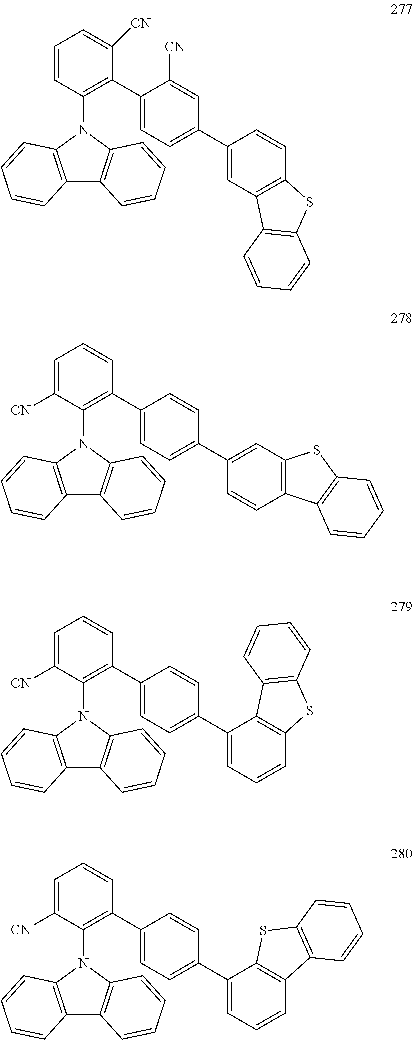

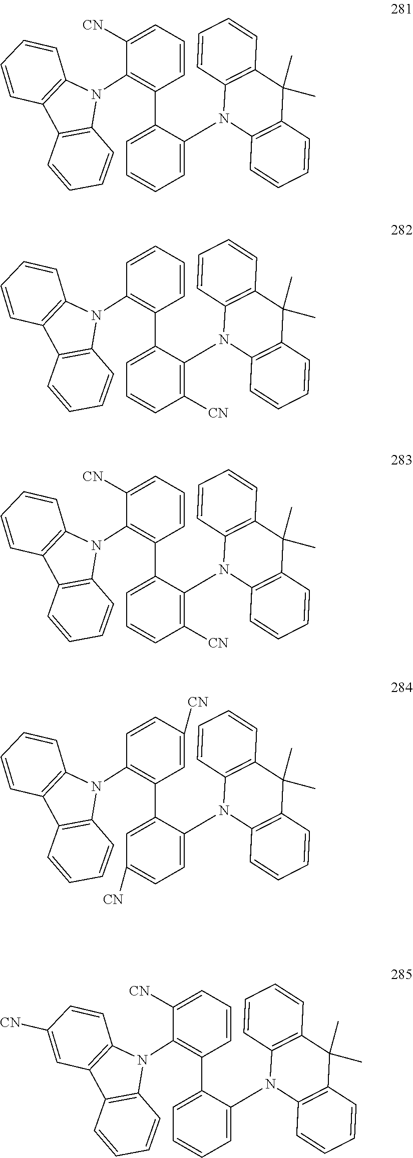

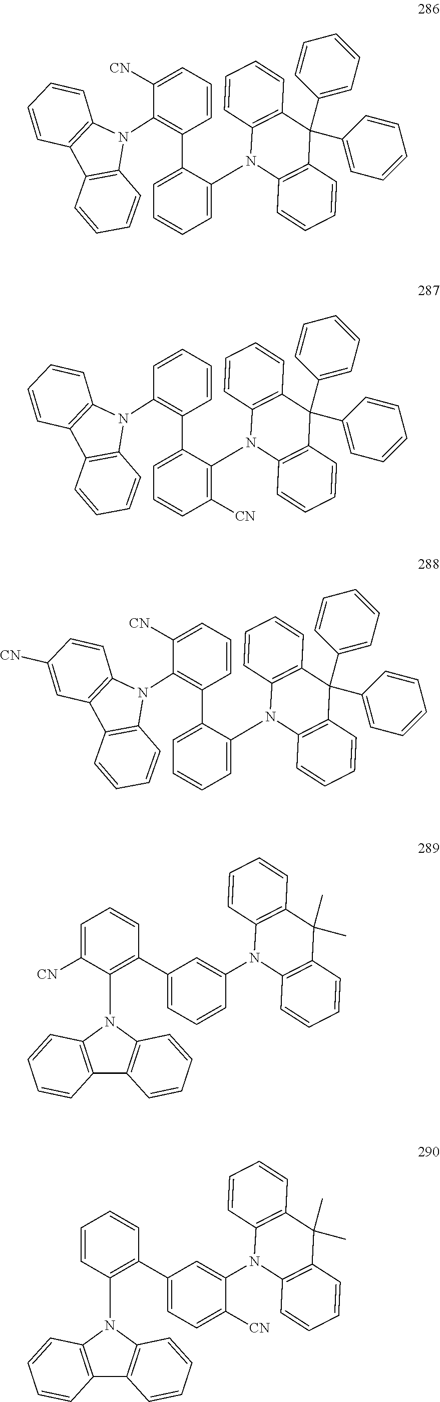

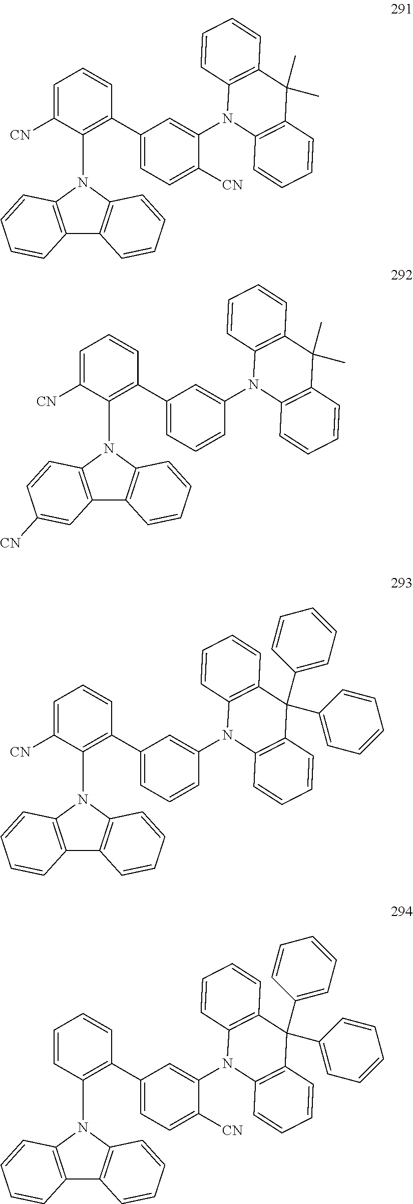

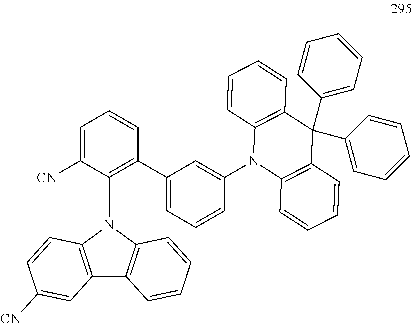

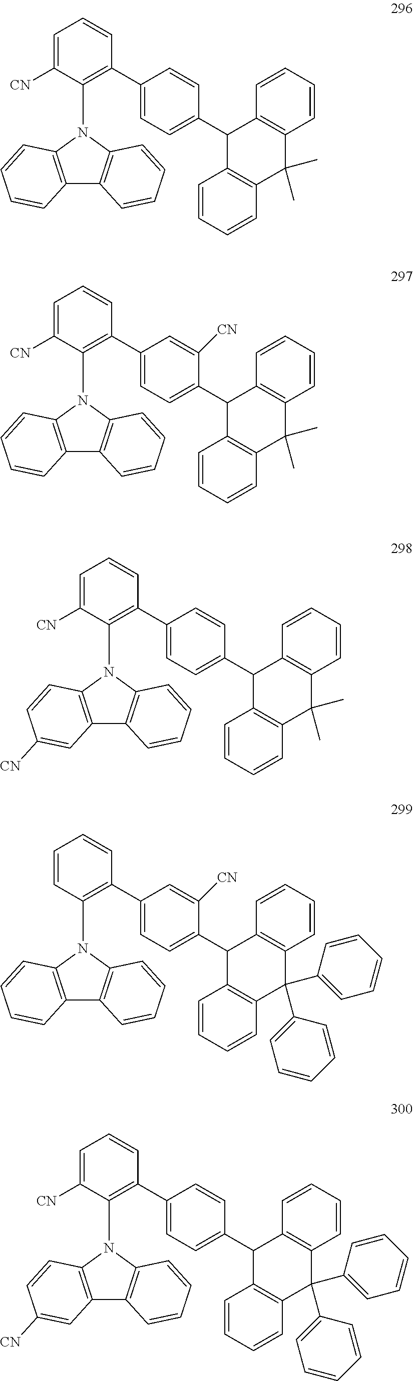

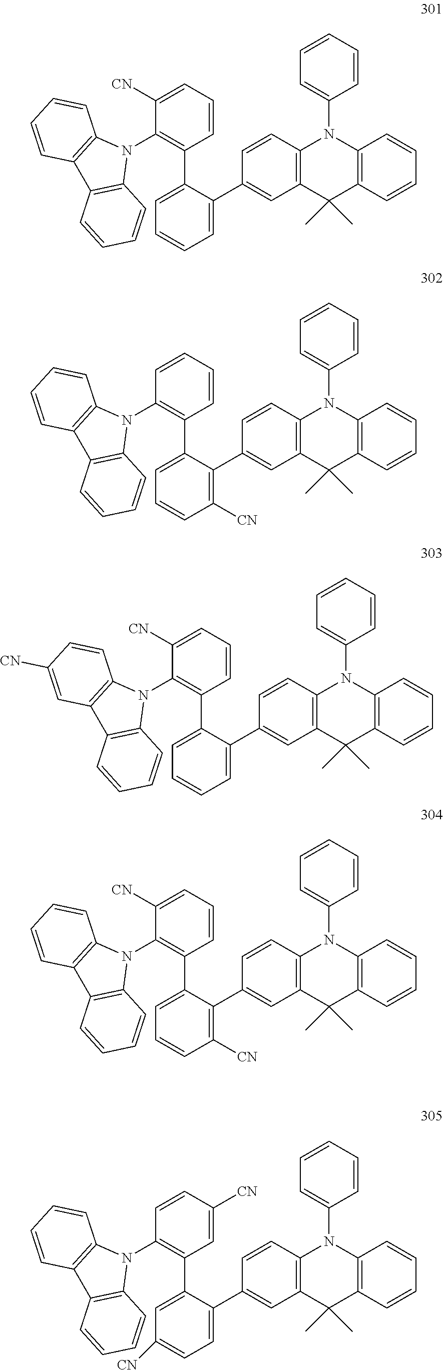

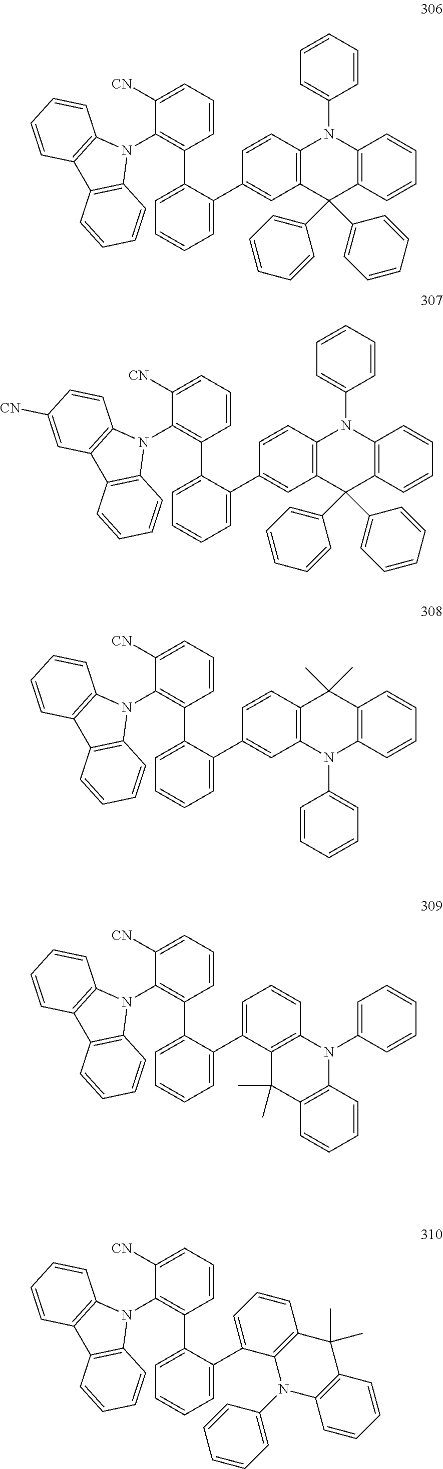

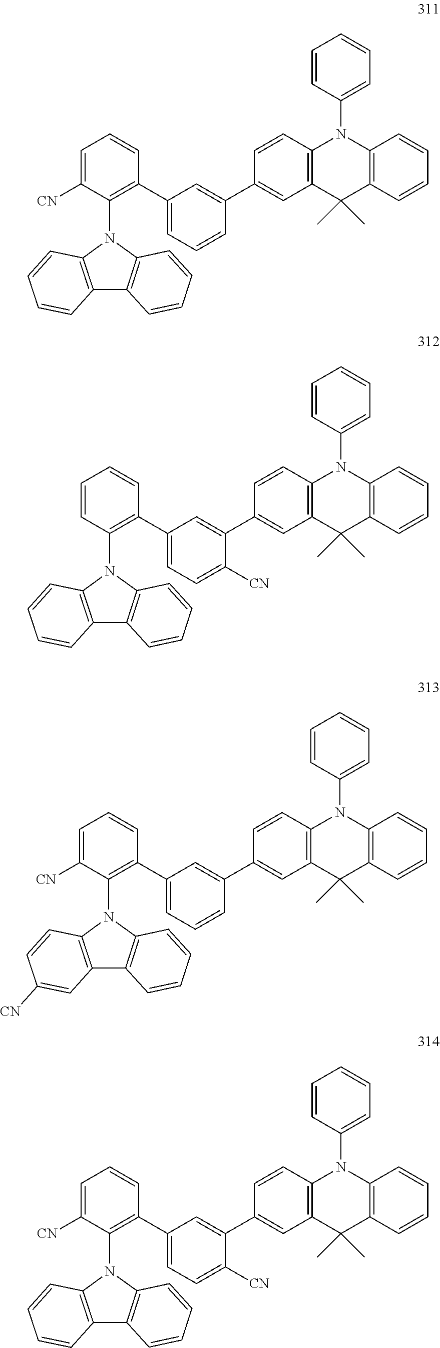

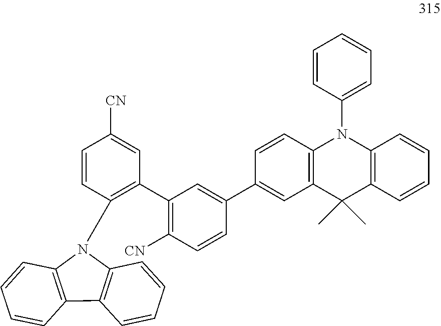

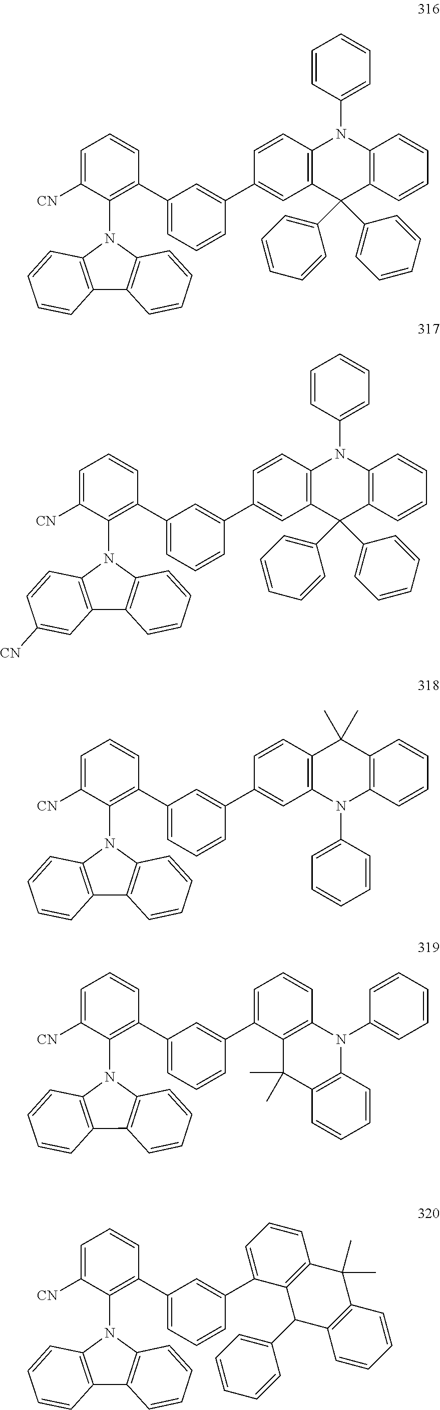

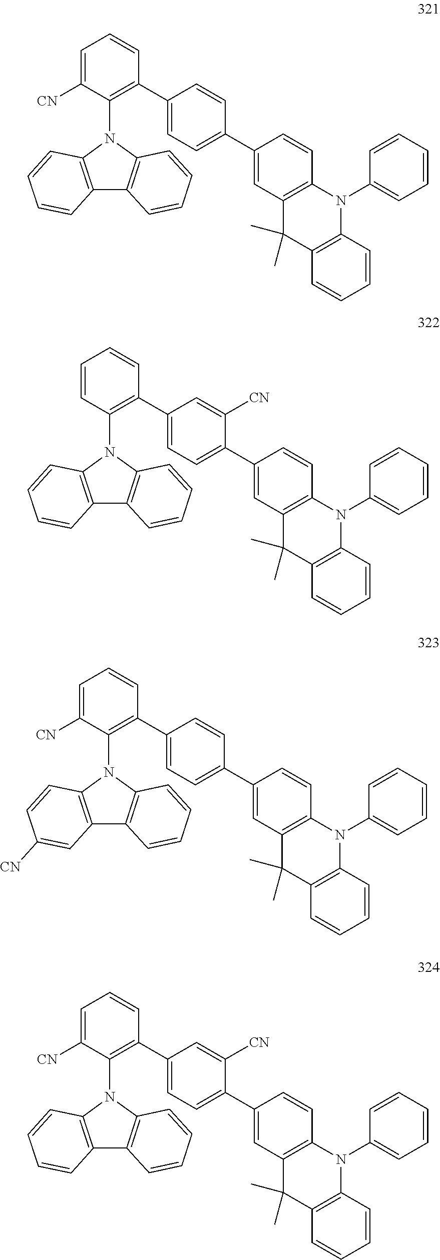

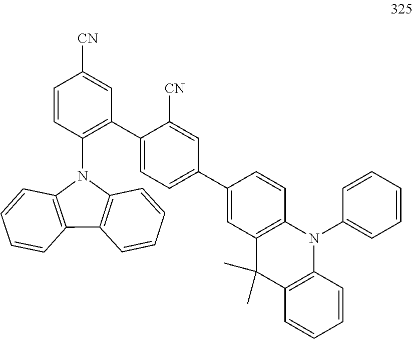 [SMILES: CC1(C)c2ccccc2N(c2ccccc2)c2ccc(-c3ccc(-c4cc(C#N)ccc4-n4c5ccccc5c5ccccc54)c(C#N)c3)cc21]

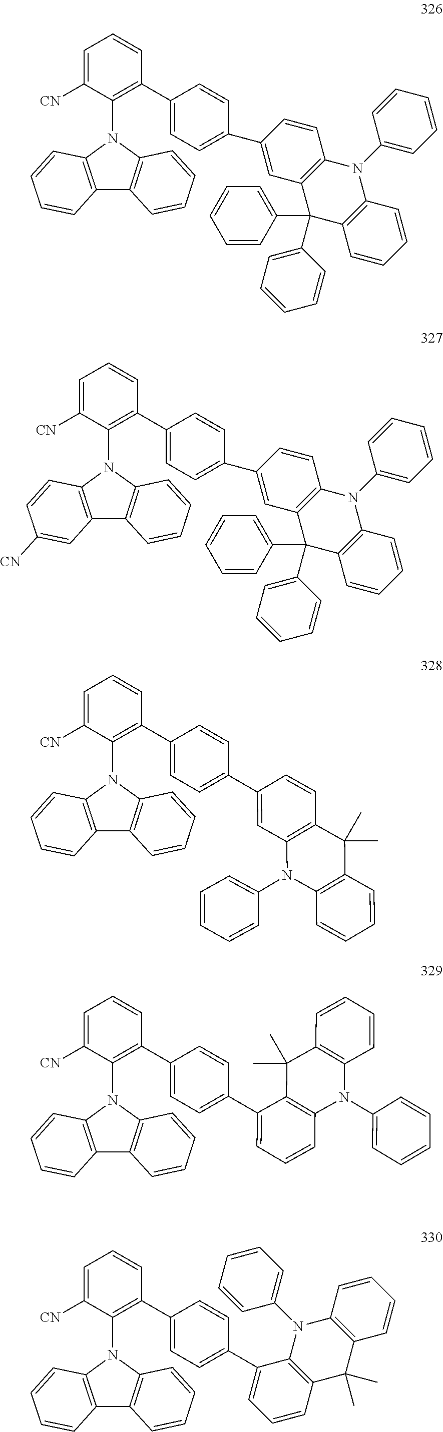

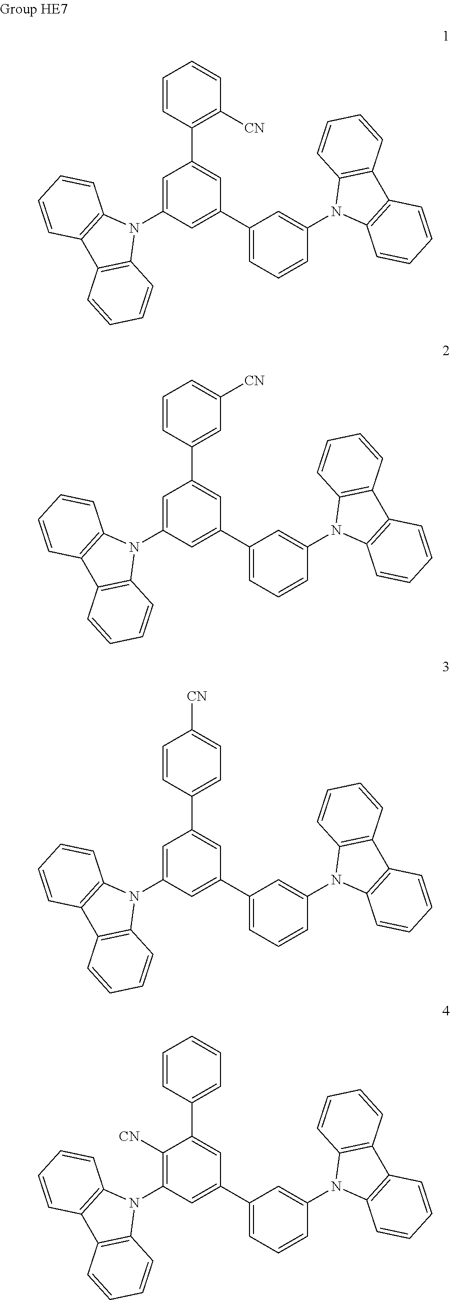

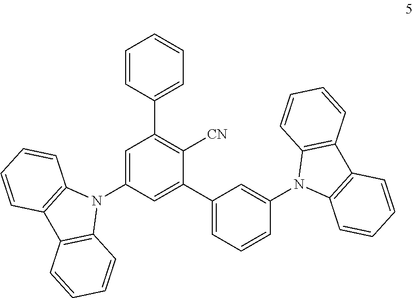 [SMILES: N#Cc1c(-c2ccccc2)cc(-n2c3ccccc3c3ccccc32)cc1-c1cccc(-n2c3ccccc3c3ccccc32)c1]

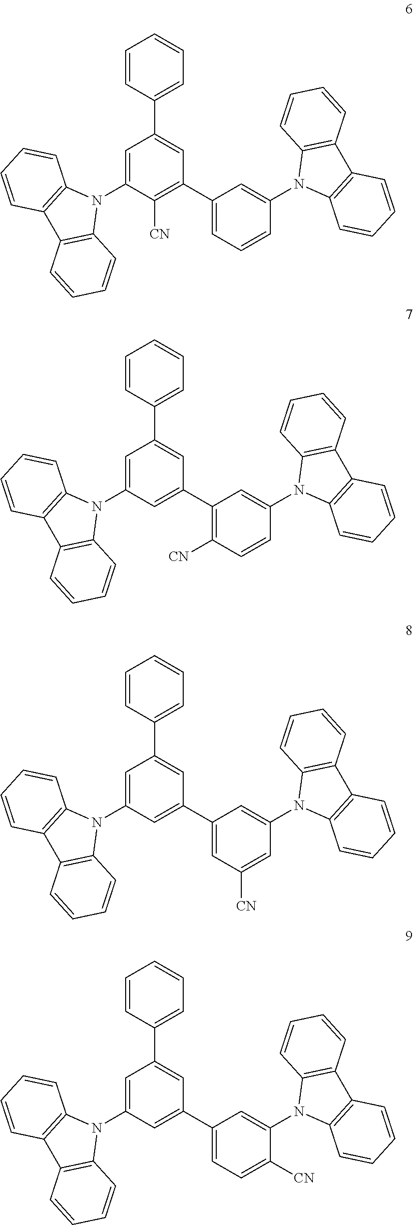

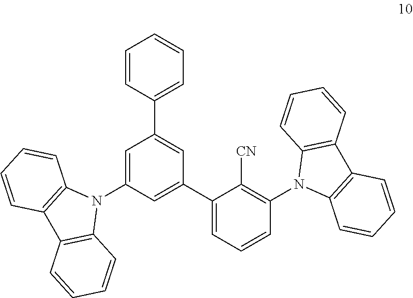 [SMILES: N#Cc1c(-c2cc(-c3ccccc3)cc(-n3c4ccccc4c4ccccc43)c2)cccc1-n1c2ccccc2c2ccccc21]

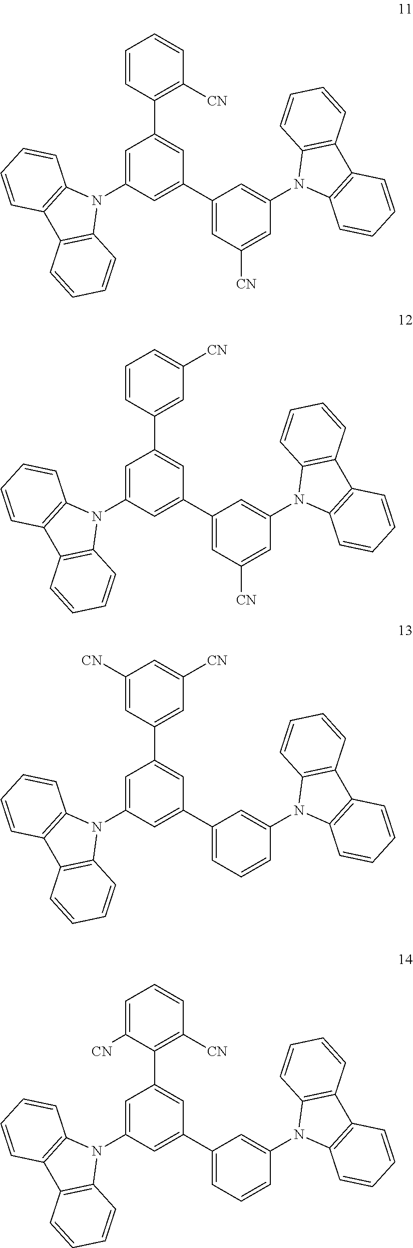

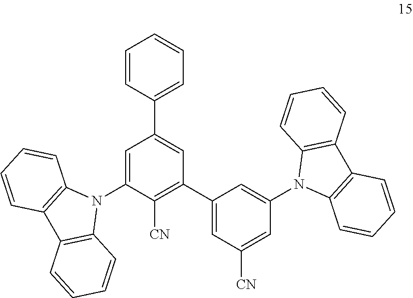 [SMILES: N#Cc1cc(-c2cc(-c3ccccc3)cc(-n3c4ccccc4c4ccccc43)c2C#N)cc(-n2c3ccccc3c3ccccc32)c1]

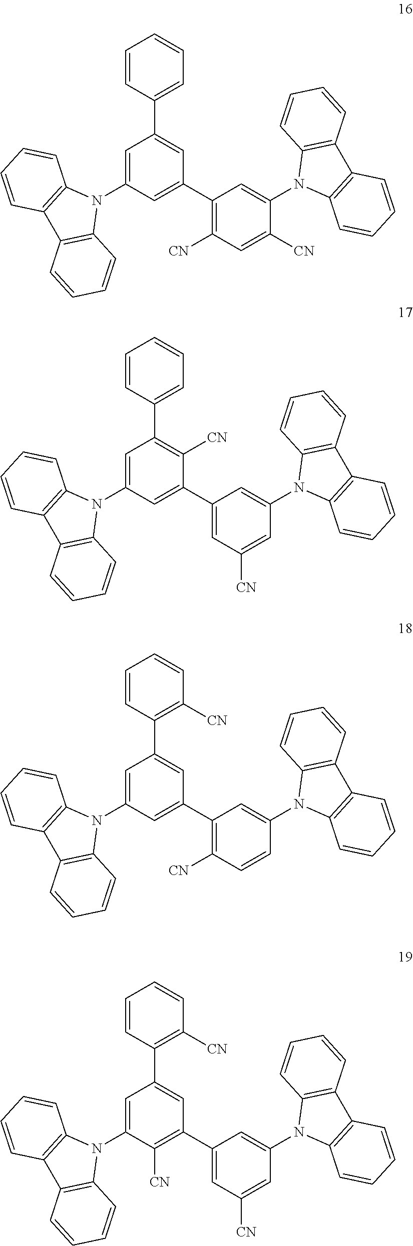

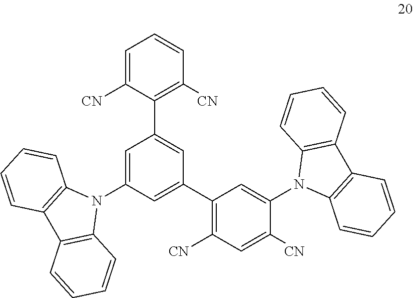

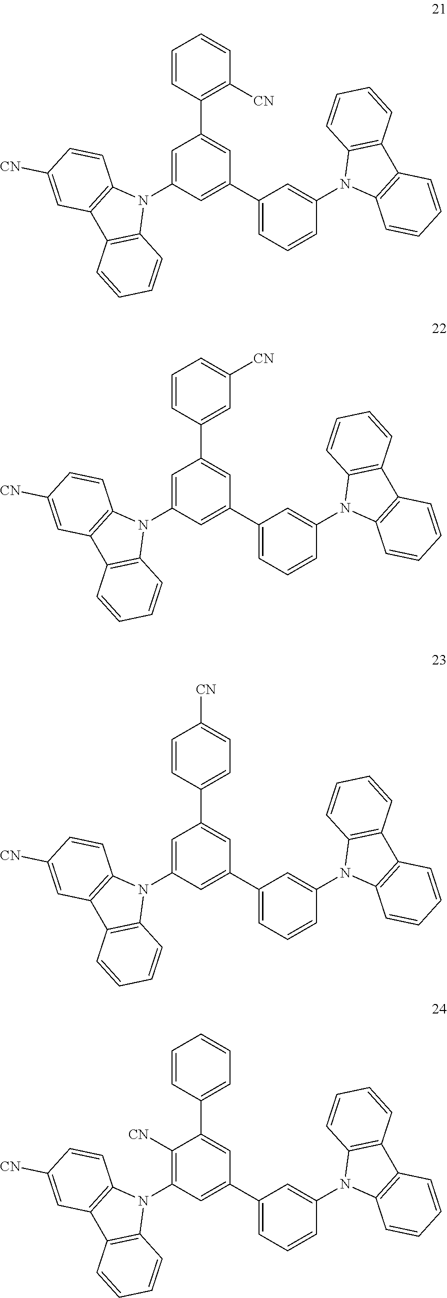

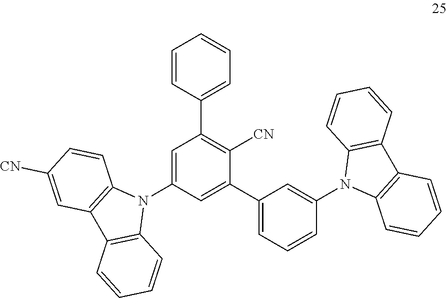

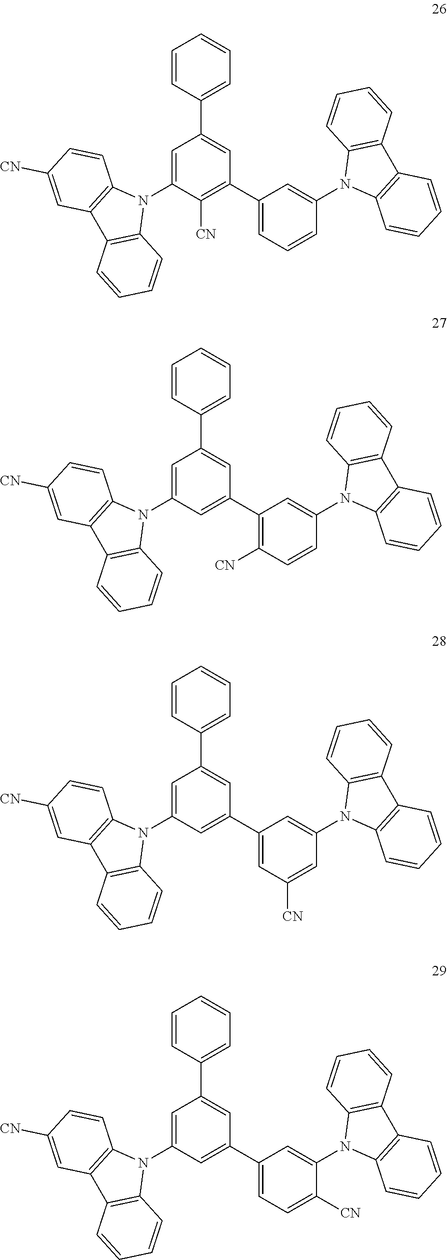

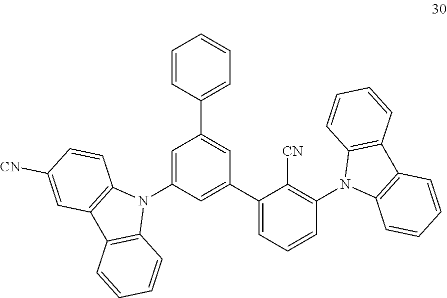

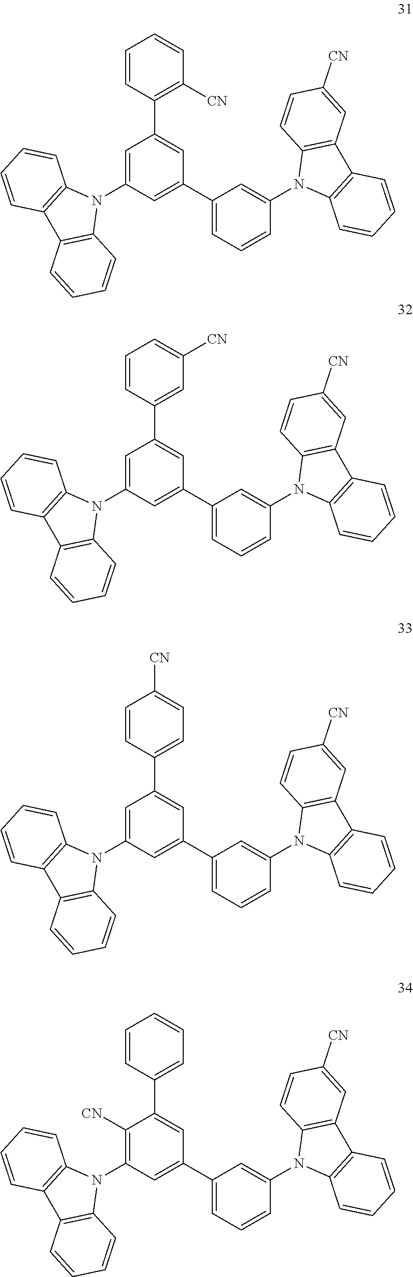

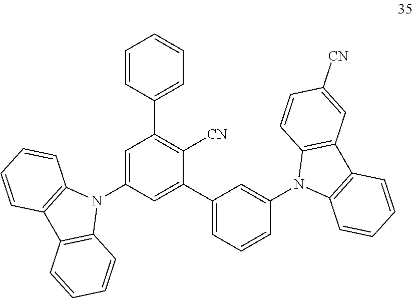 [SMILES: N#Cc1ccc2c(c1)c1ccccc1n2-c1cccc(-c2cc(-n3c4ccccc4c4ccccc43)cc(-c3ccccc3)c2C#N)c1]

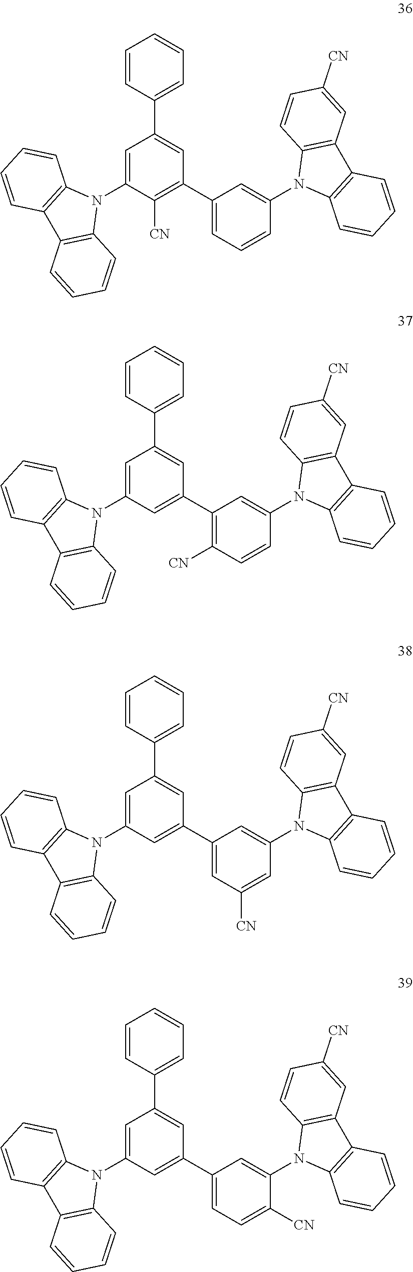

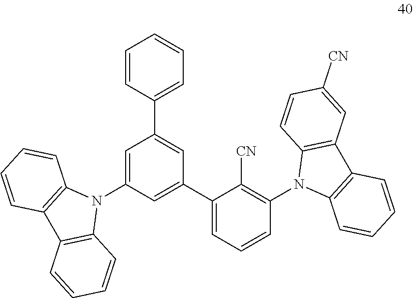 [SMILES: N#Cc1ccc2c(c1)c1ccccc1n2-c1cccc(-c2cc(-c3ccccc3)cc(-n3c4ccccc4c4ccccc43)c2)c1C#N]

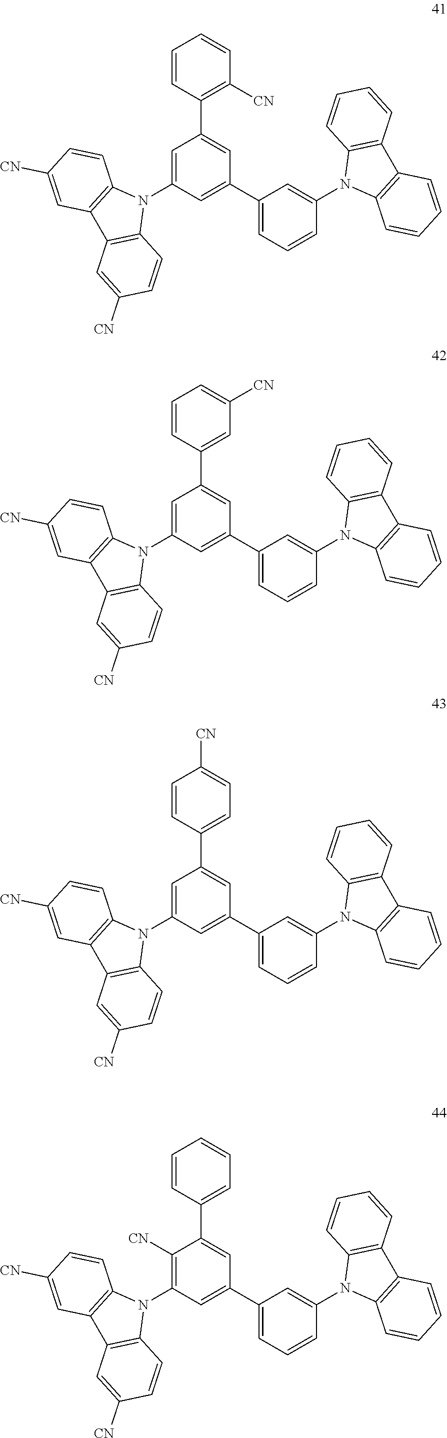

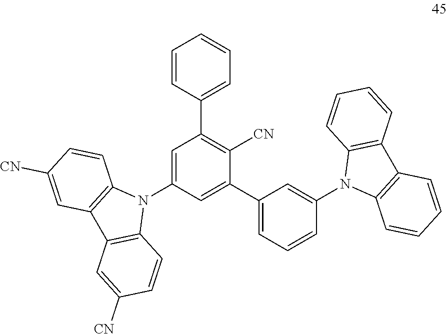

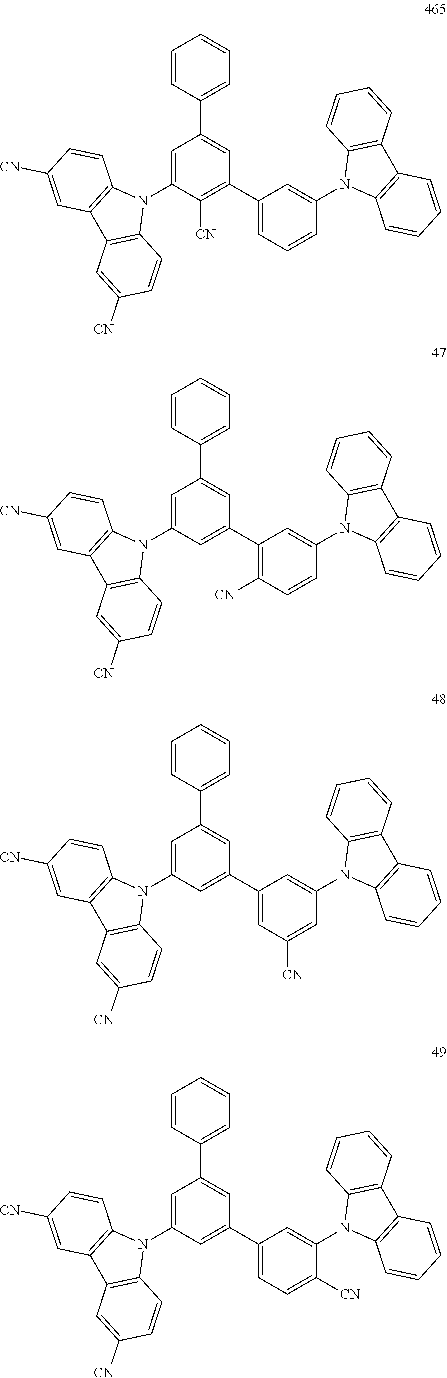

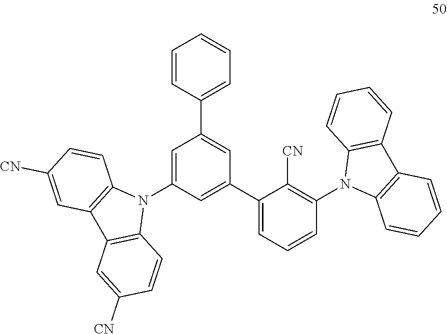

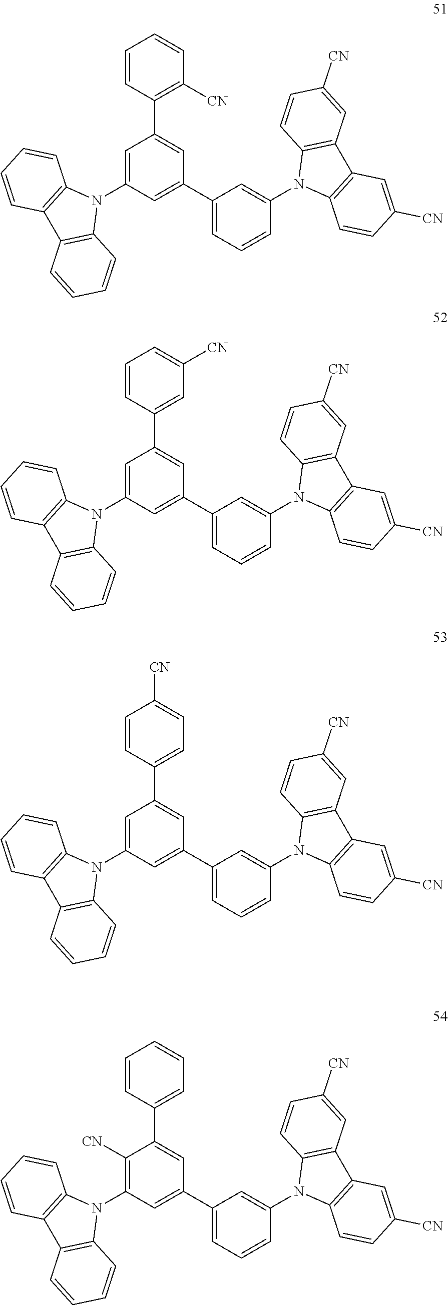

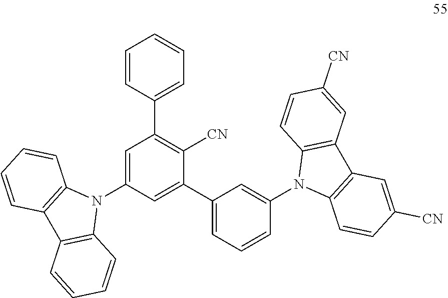 [SMILES: N#Cc1ccc2c(c1)c1cc(C#N)ccc1n2-c1cccc(-c2cc(-n3c4ccccc4c4ccccc43)cc(-c3ccccc3)c2C#N)c1]

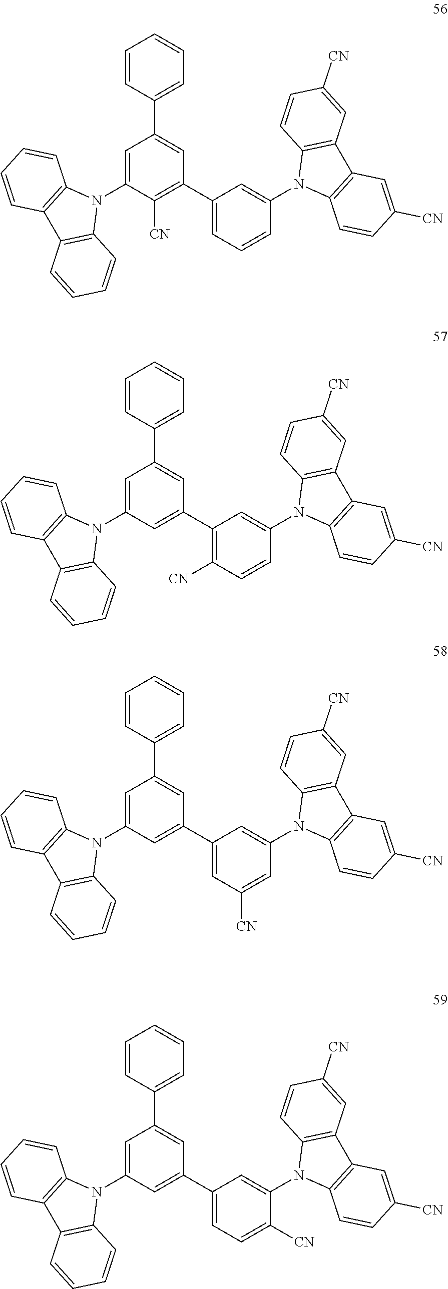

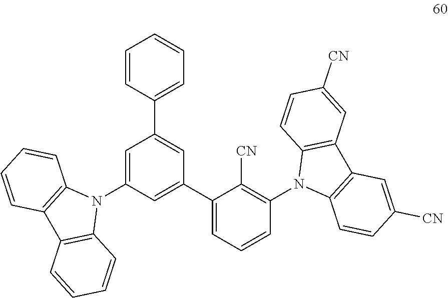 [SMILES: N#Cc1ccc2c(c1)c1cc(C#N)ccc1n2-c1cccc(-c2cc(-c3ccccc3)cc(-n3c4ccccc4c4ccccc43)c2)c1C#N]

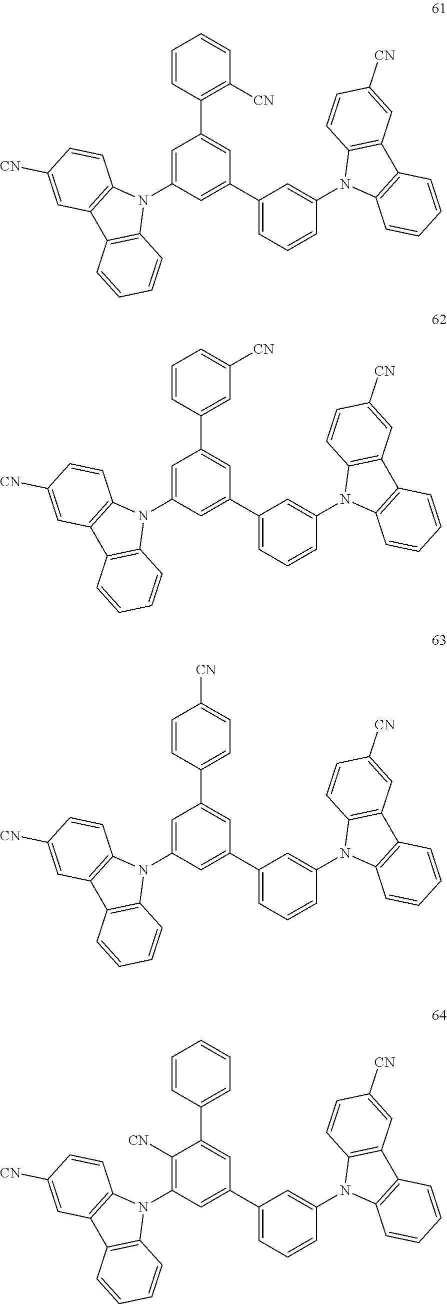

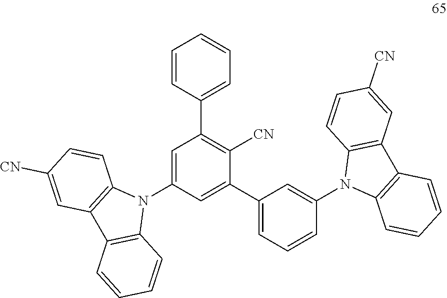

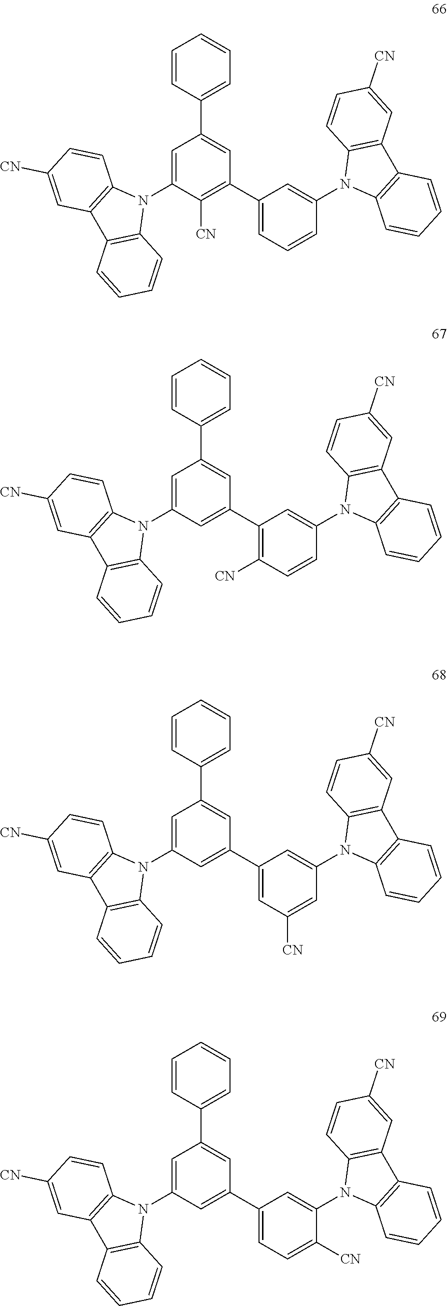

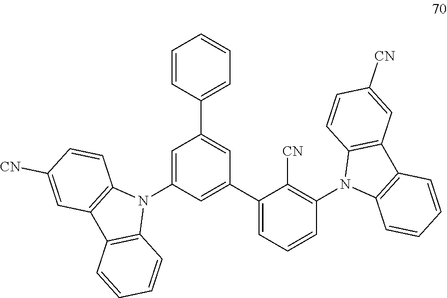

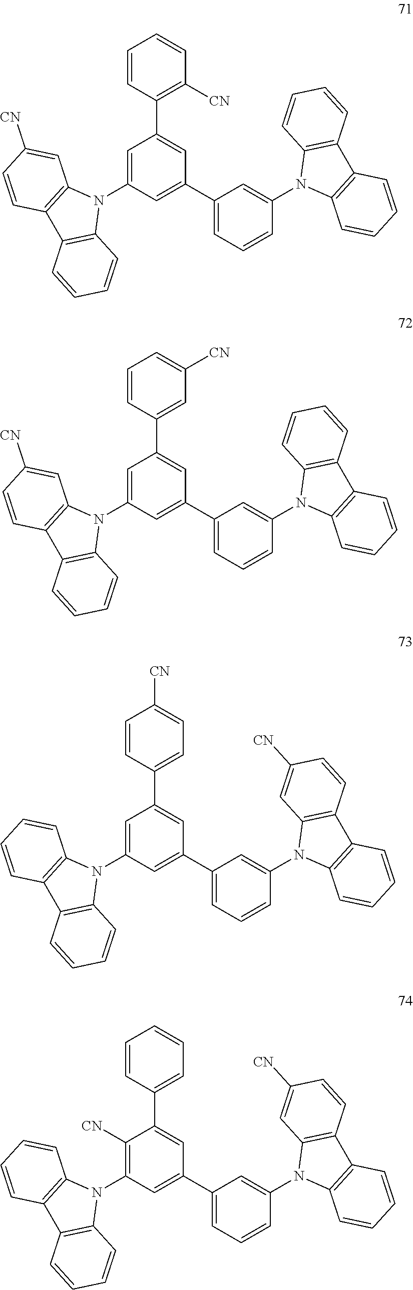

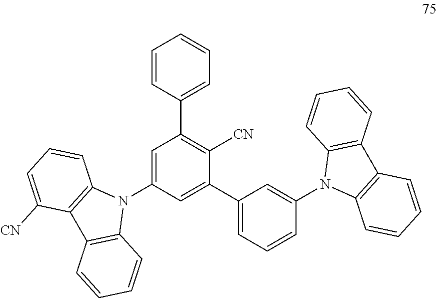

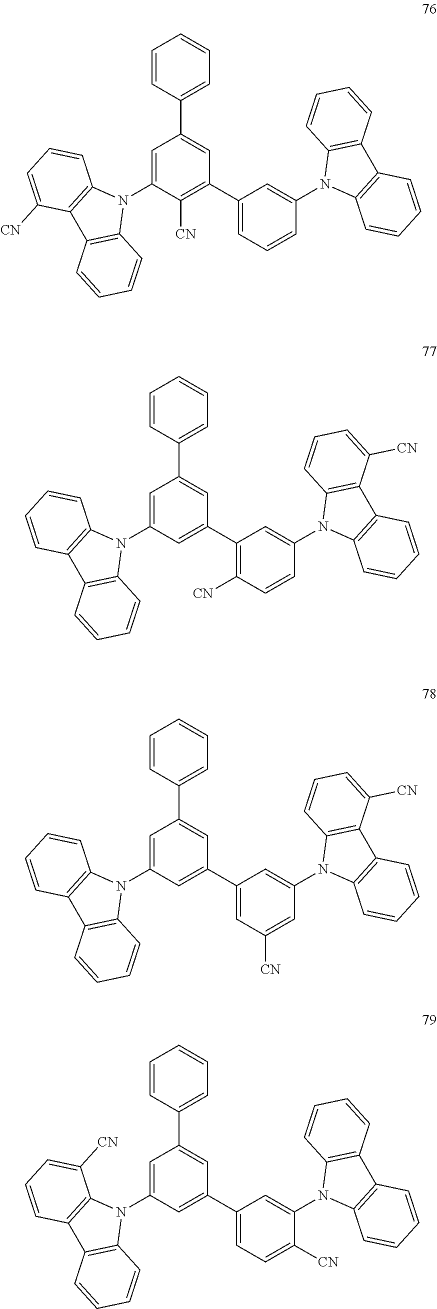

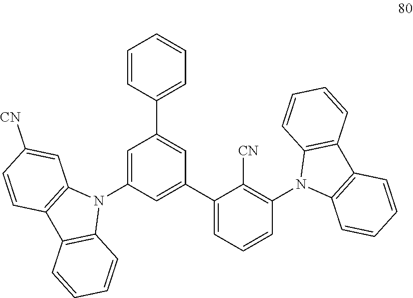

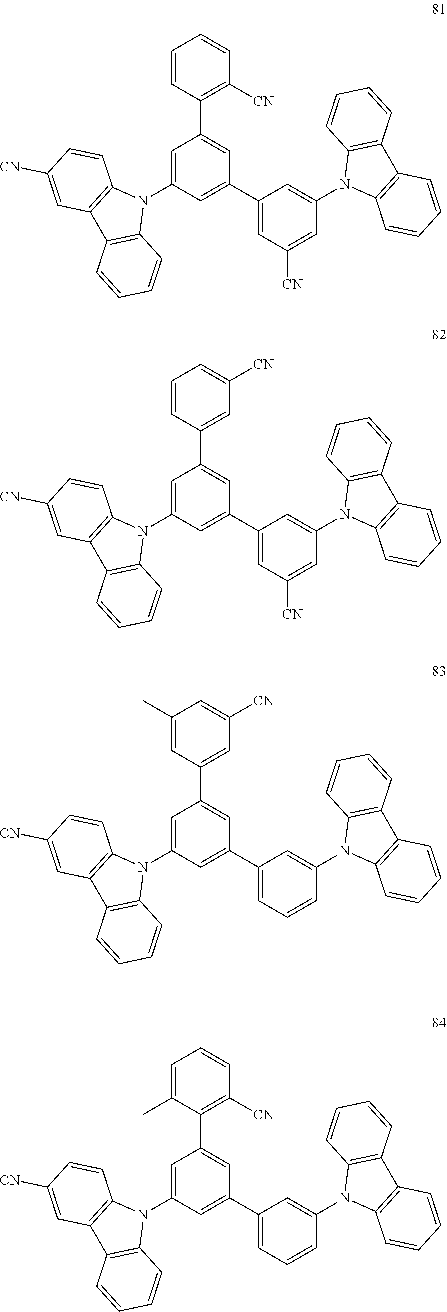

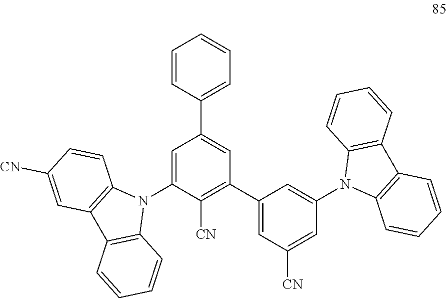

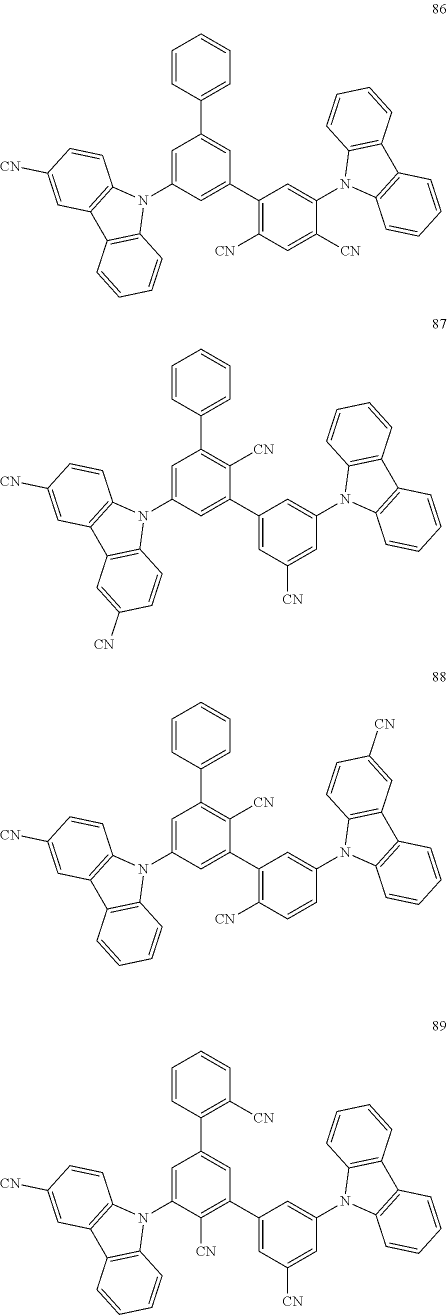

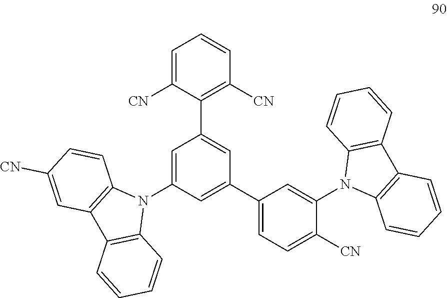

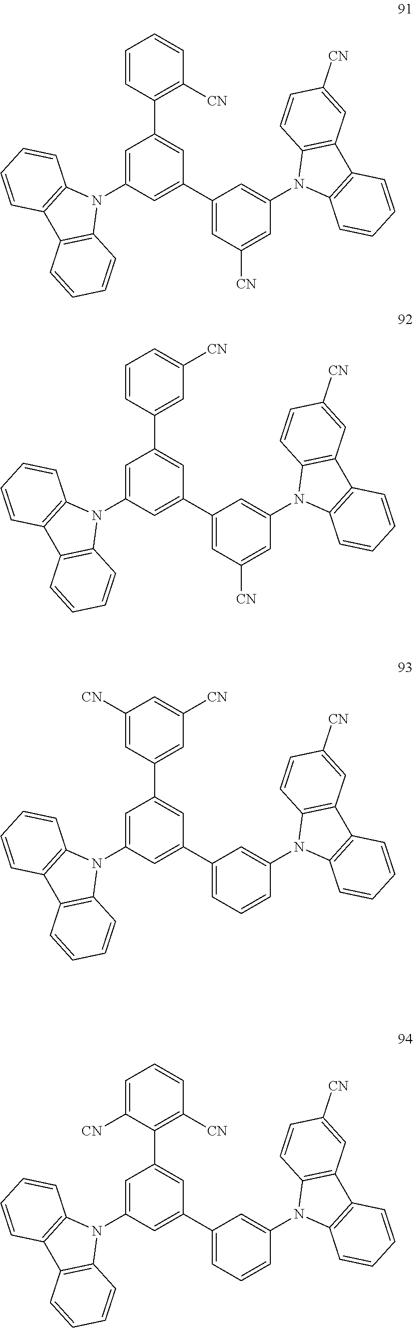

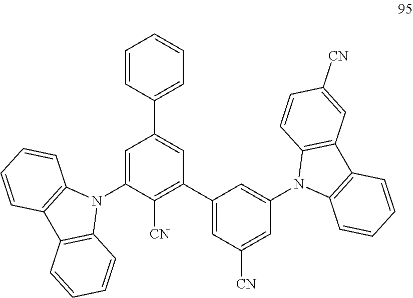 [SMILES: N#Cc1cc(-c2cc(-c3ccccc3)cc(-n3c4ccccc4c4ccccc43)c2C#N)cc(-n2c3ccccc3c3cc(C#N)ccc32)c1]

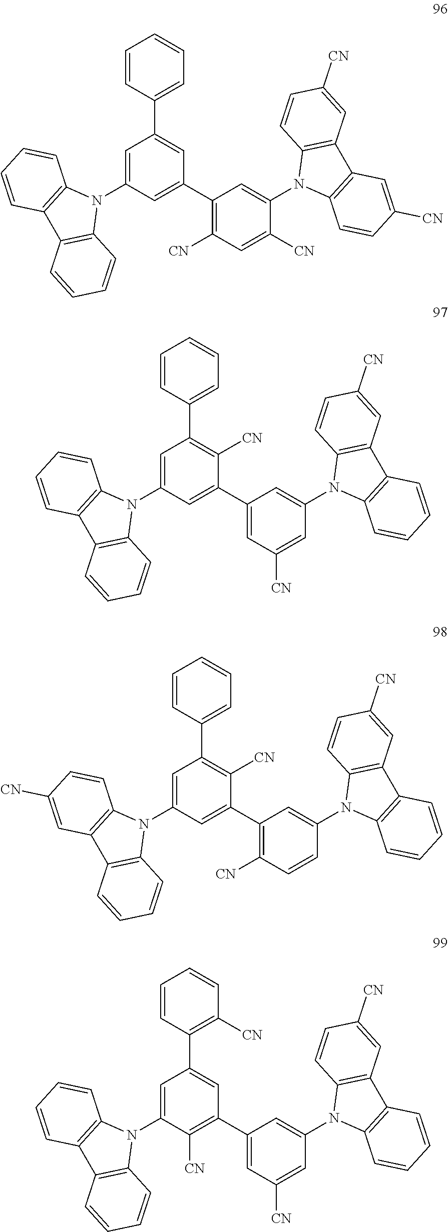

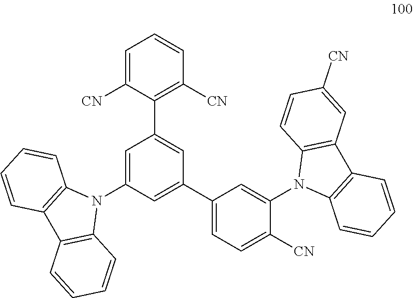

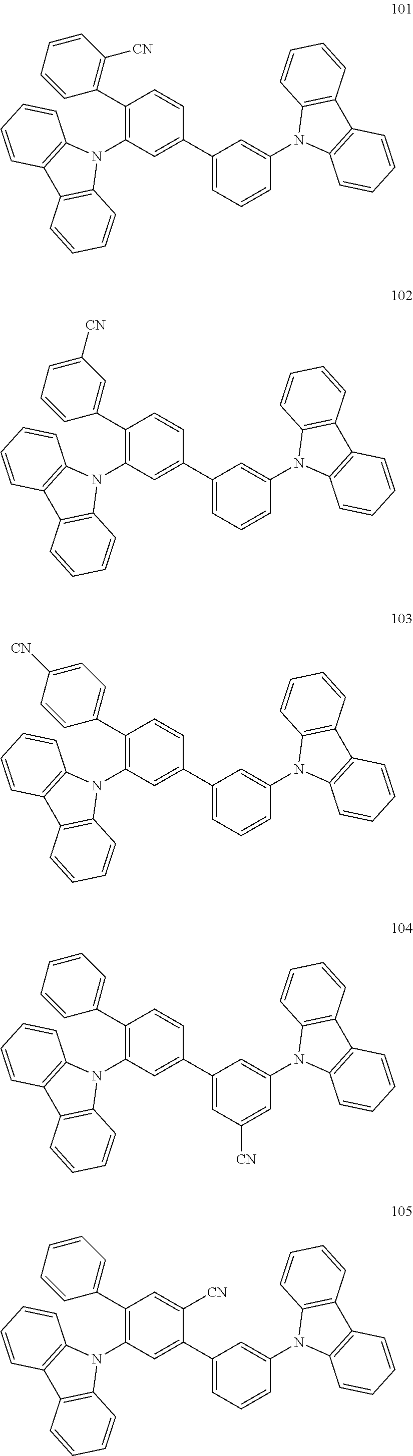

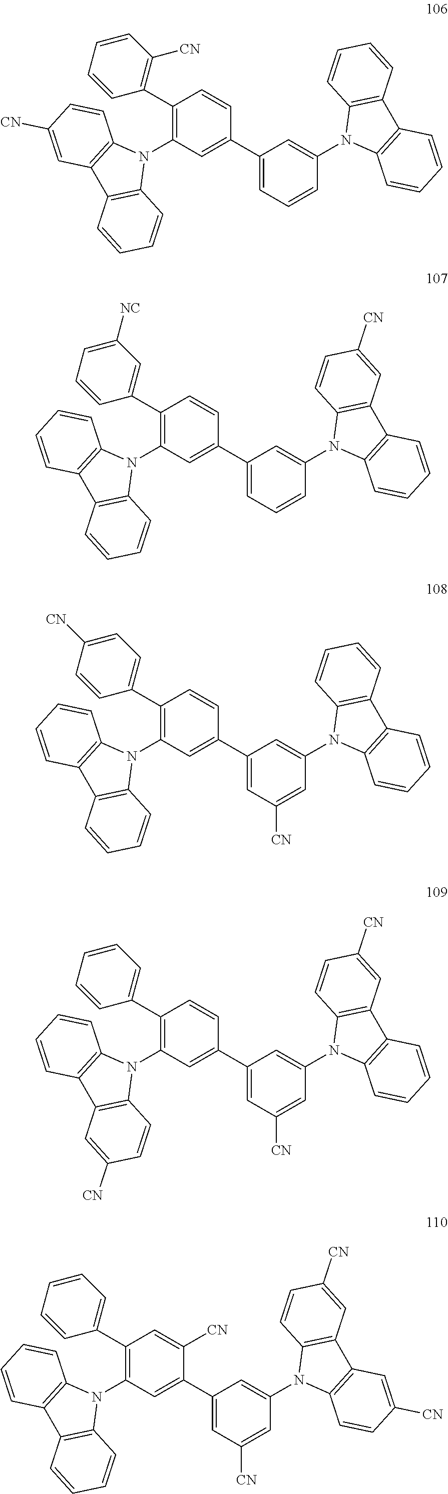

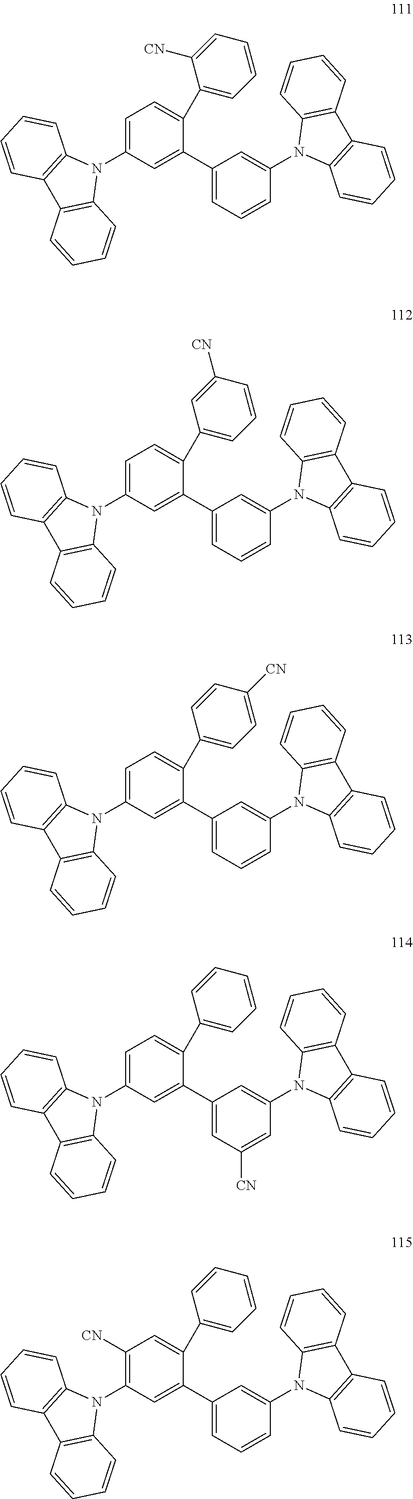

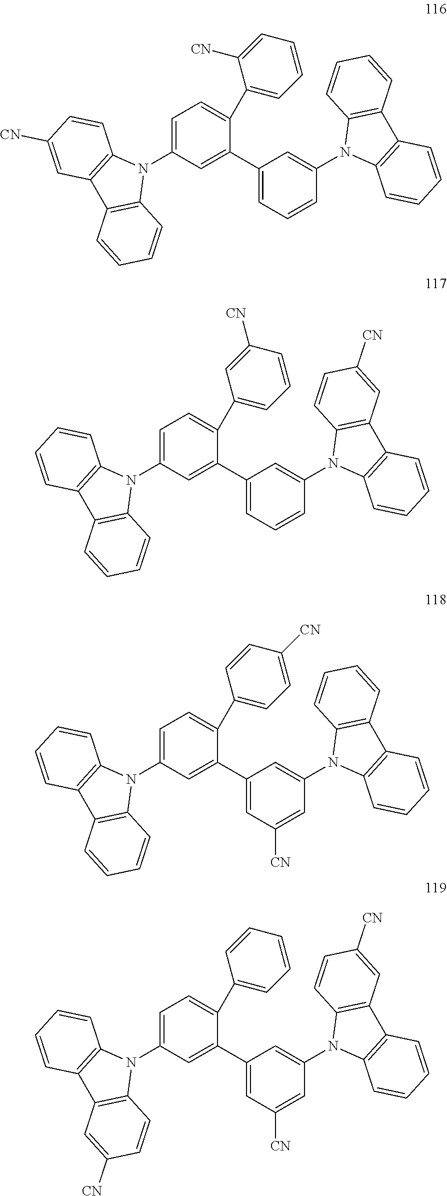

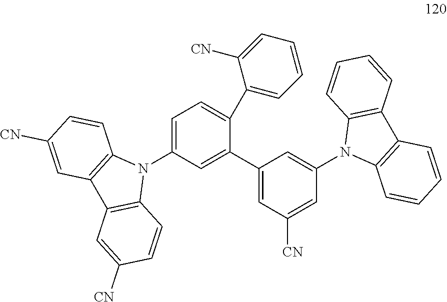

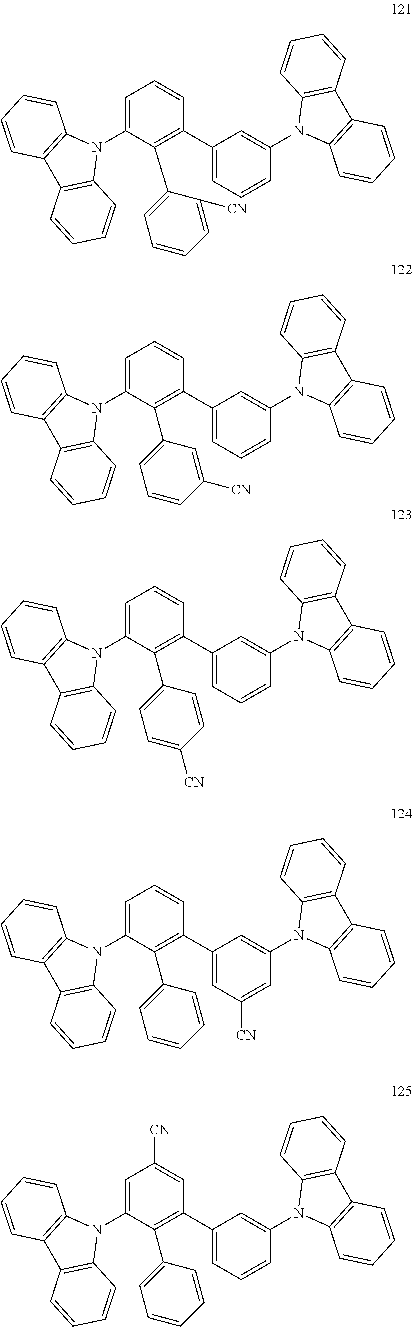 [SMILES: N#Cc1ccccc1-c1c(-c2cccc(-n3c4ccccc4c4ccccc43)c2)cccc1-n1c2ccccc2c2ccccc21 ; N#Cc1cccc(-c2c(-c3cccc(-n4c5ccccc5c5ccccc54)c3)cccc2-n2c3ccccc3c3ccccc32)c1 ; N#Cc1ccc(-c2c(-c3cccc(-n4c5ccccc5c5ccccc54)c3)cccc2-n2c3ccccc3c3ccccc32)cc1 ; N#Cc1cc(-c2cccc(-n3c4ccccc4c4ccccc43)c2-c2ccccc2)cc(-n2c3ccccc3c3ccccc32)c1 ; N#Cc1cc(-c2cccc(-n3c4ccccc4c4ccccc43)c2)c(-c2ccccc2)c(-n2c3ccccc3c3ccccc32)c1]

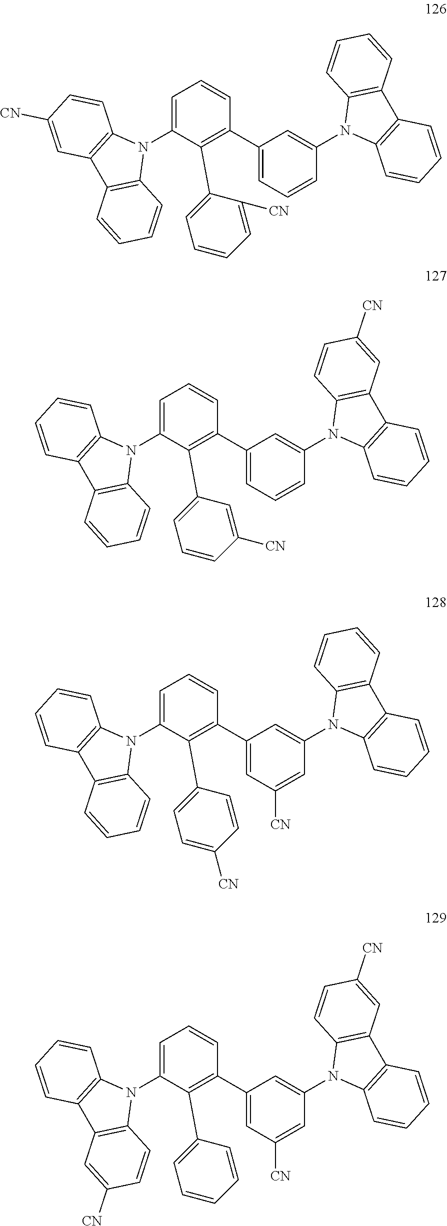

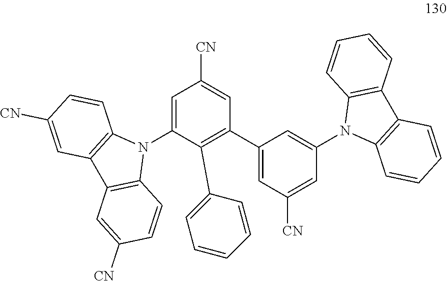

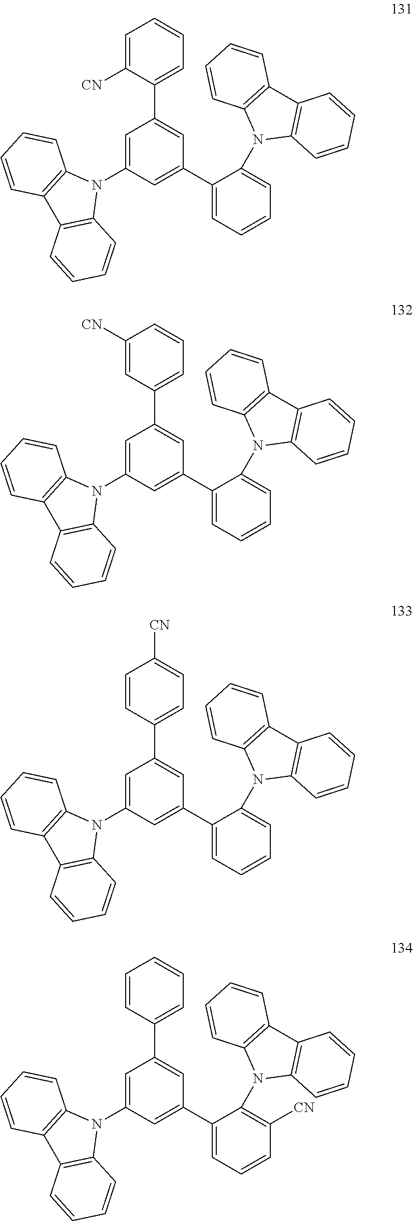

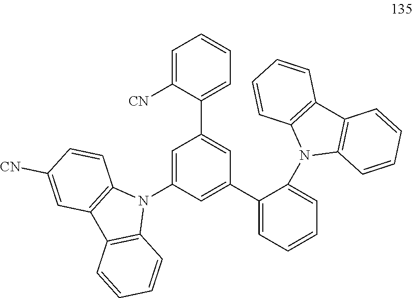

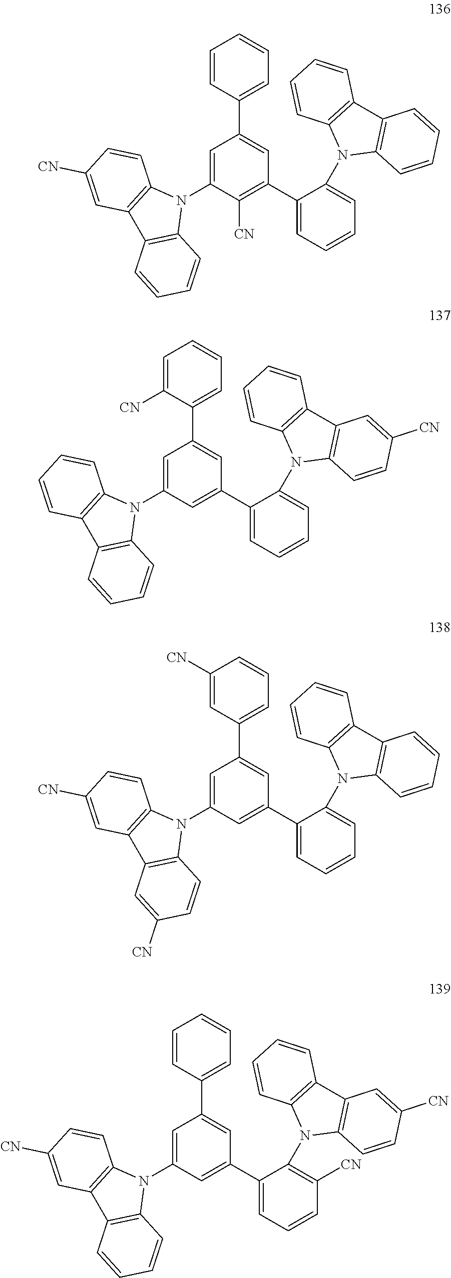

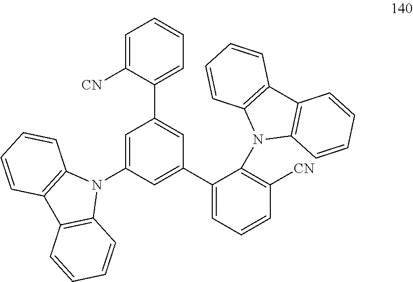

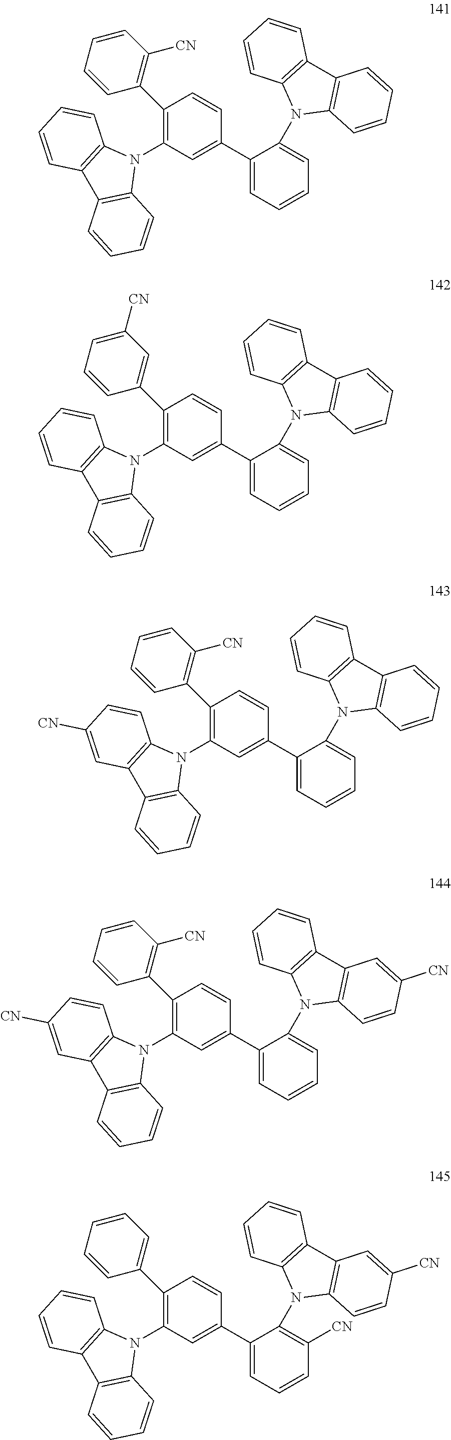

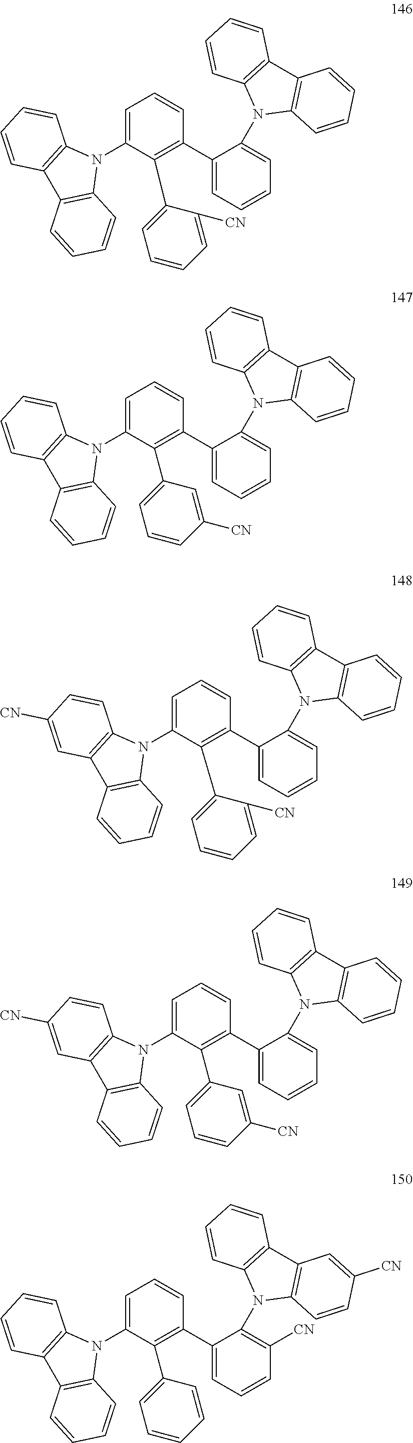

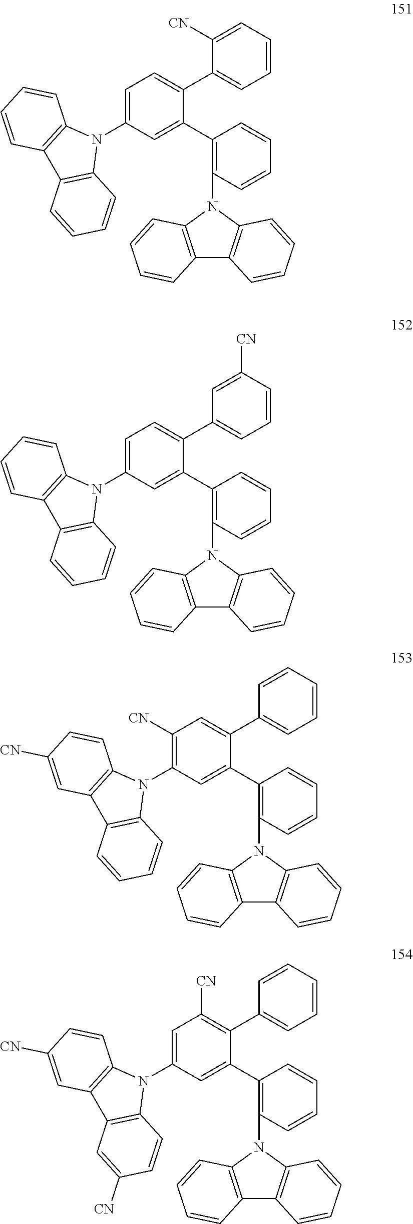

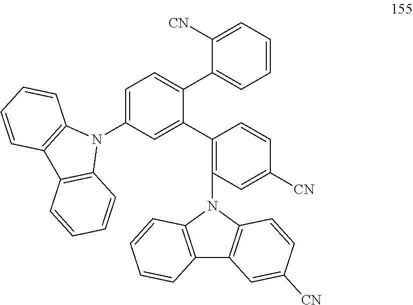

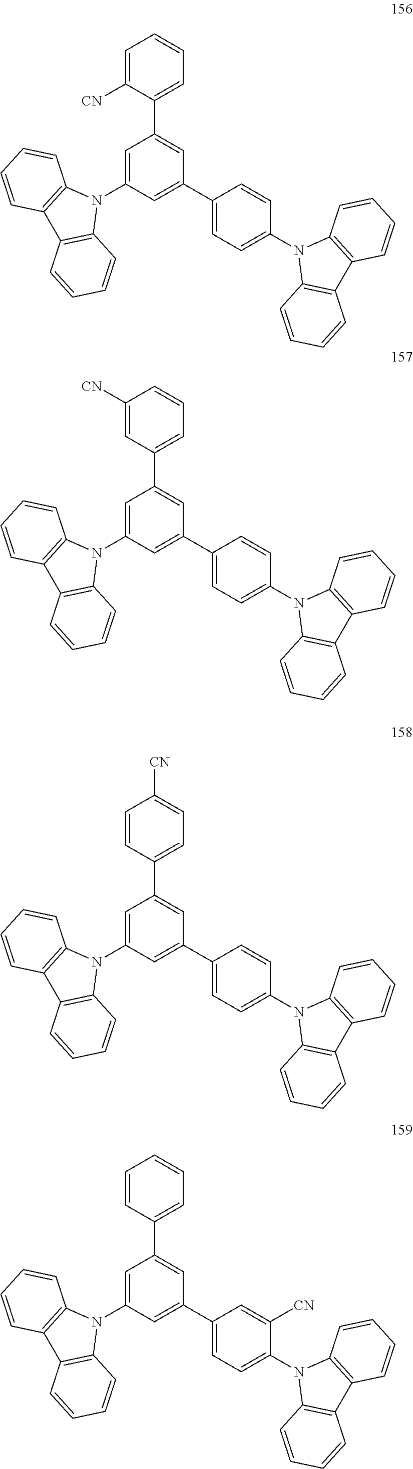

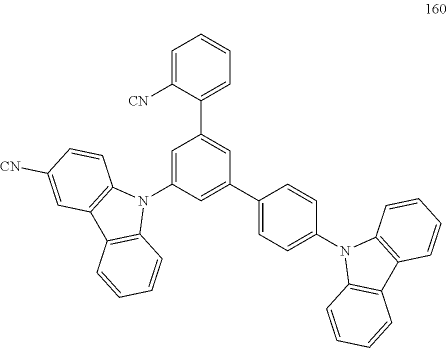

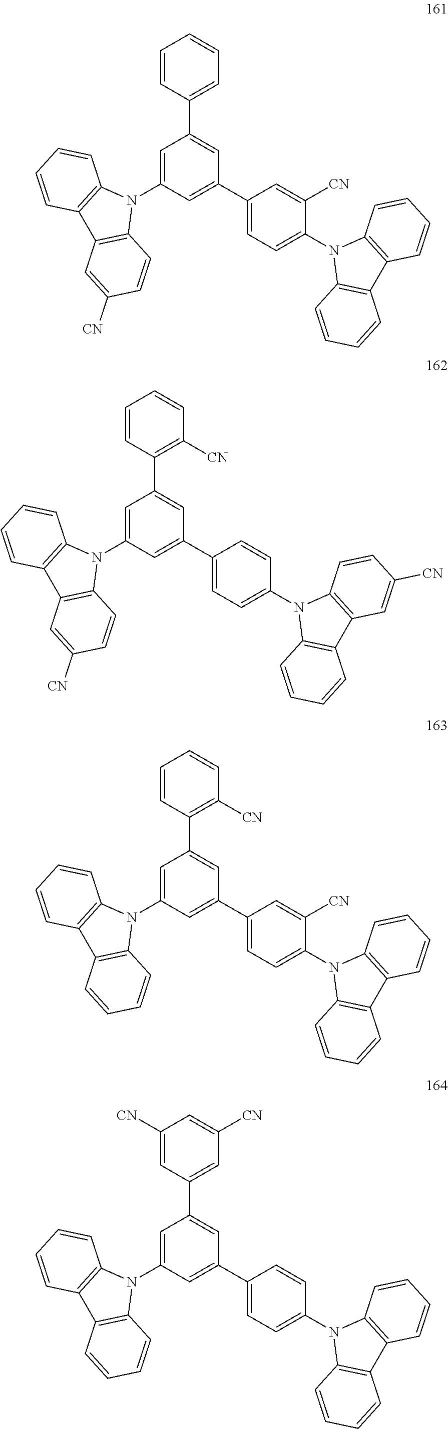

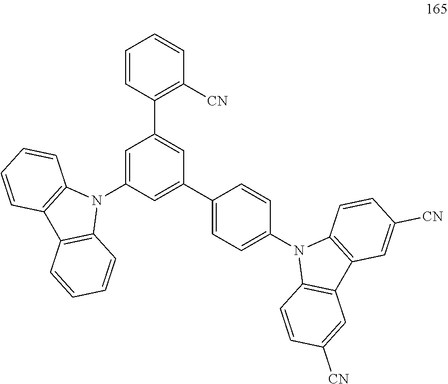 [SMILES: N#Cc1ccc2c(c1)c1cc(C#N)ccc1n2-c1ccc(-c2cc(-c3ccccc3C#N)cc(-n3c4ccccc4c4ccccc43)c2)cc1]

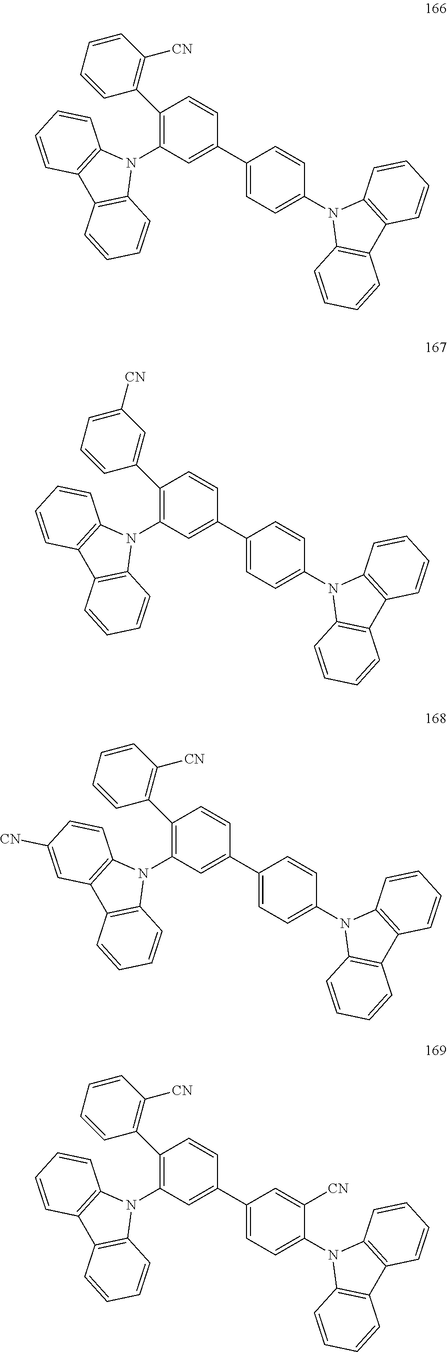

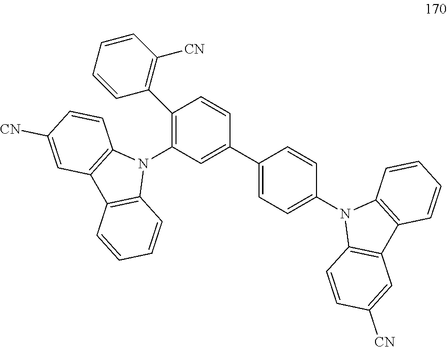

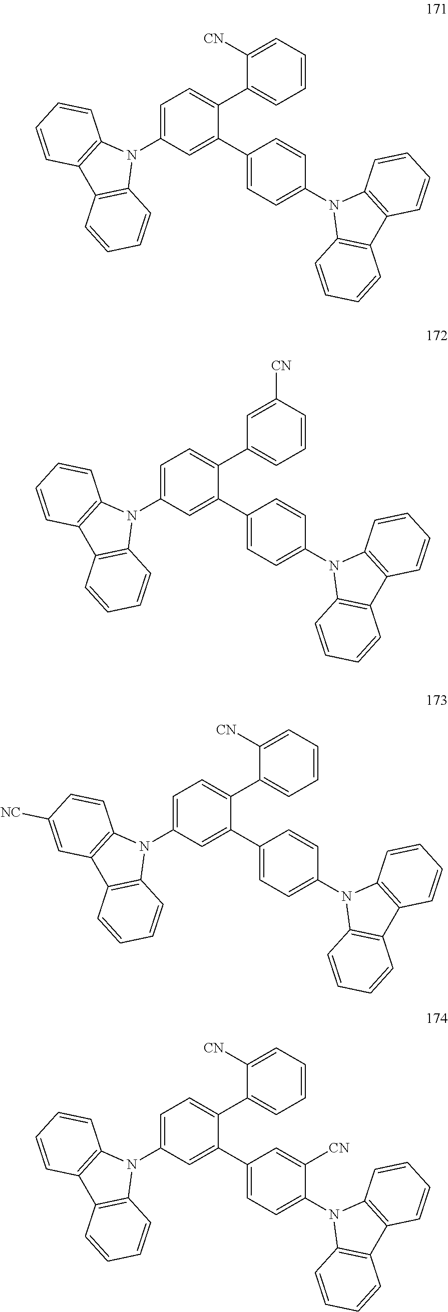

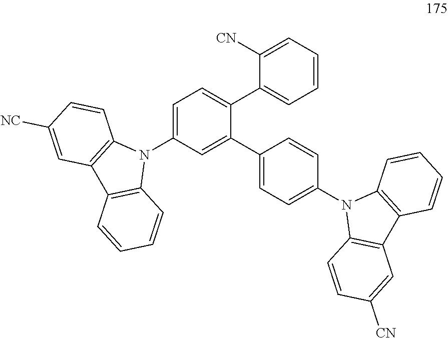

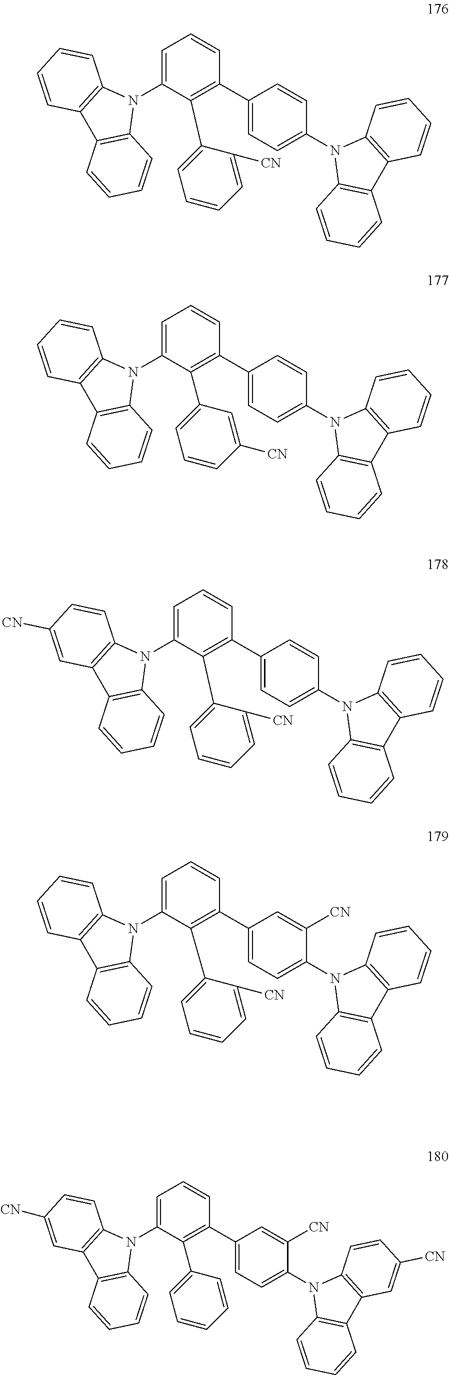

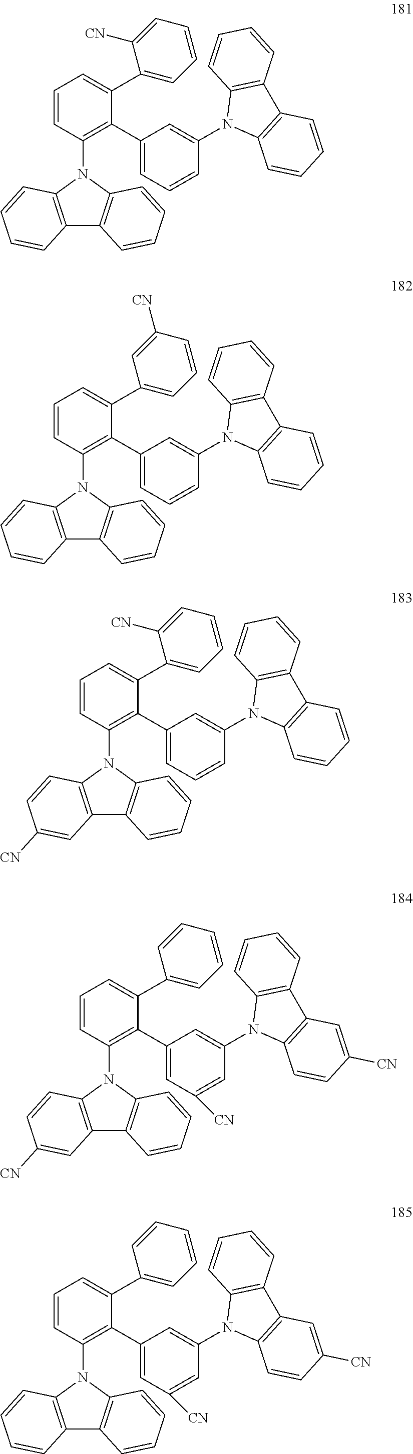

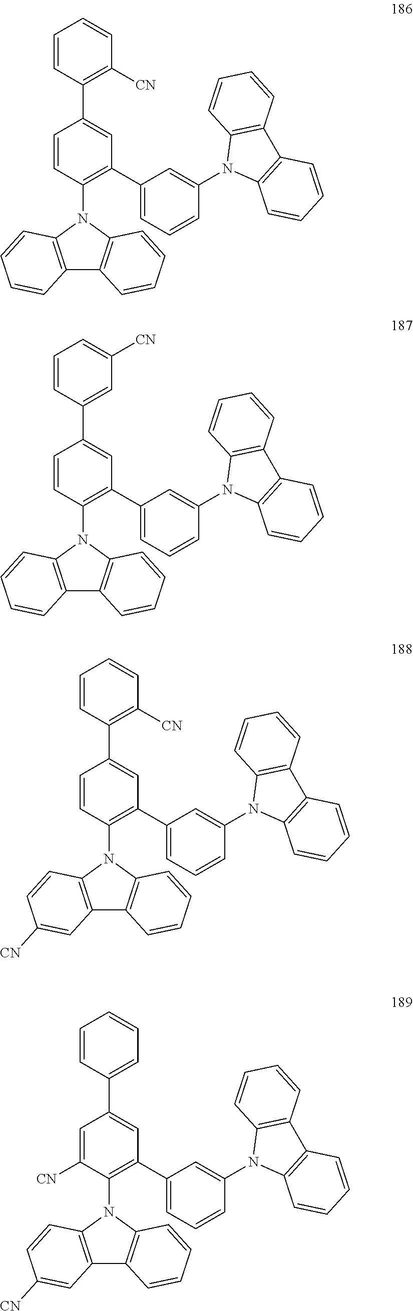

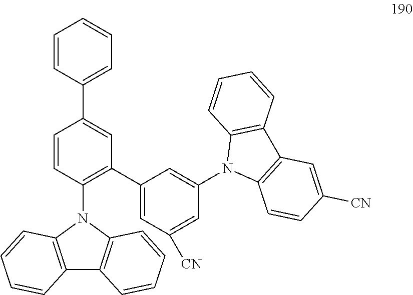 [SMILES: N#Cc1cc(-c2cc(-c3ccccc3)ccc2-n2c3ccccc3c3ccccc32)cc(-n2c3ccccc3c3cc(C#N)ccc32)c1]

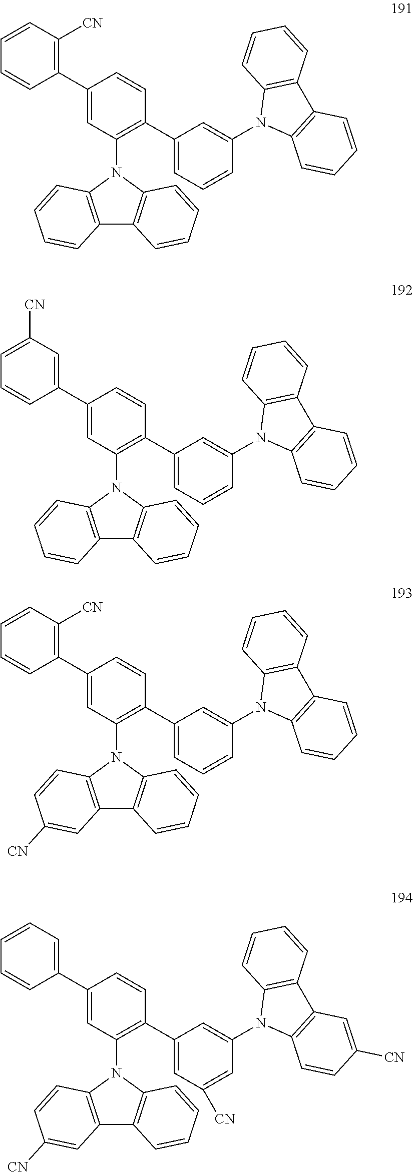

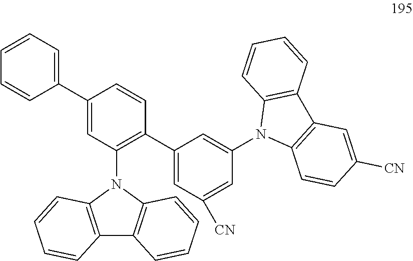 [SMILES: N#Cc1cc(-c2ccc(-c3ccccc3)cc2-n2c3ccccc3c3ccccc32)cc(-n2c3ccccc3c3cc(C#N)ccc32)c1]

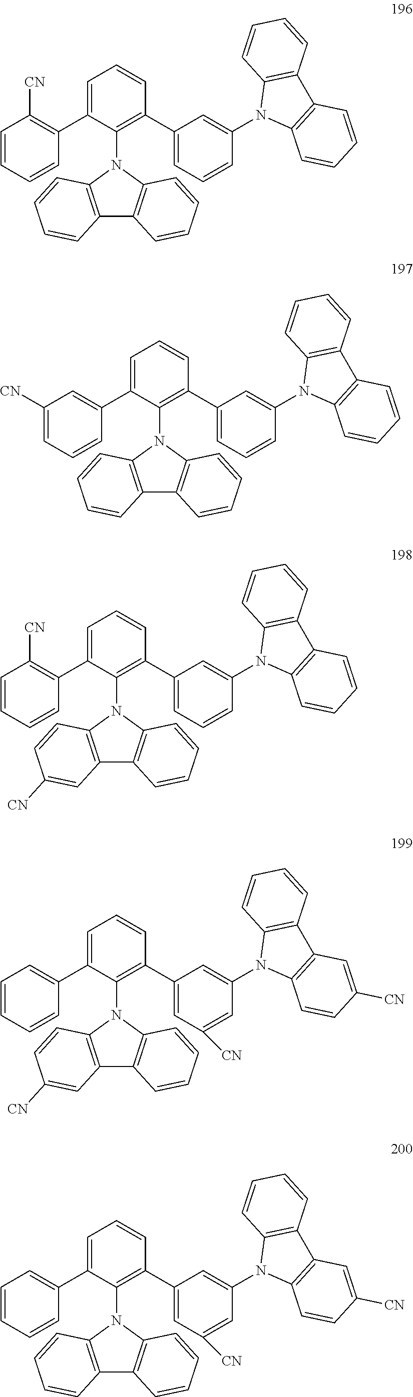

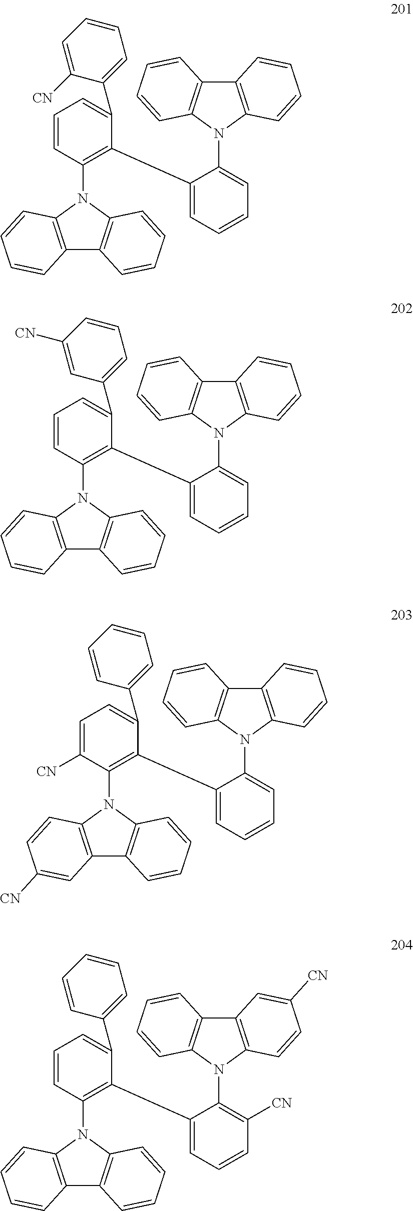

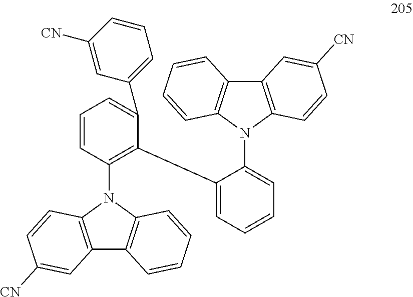

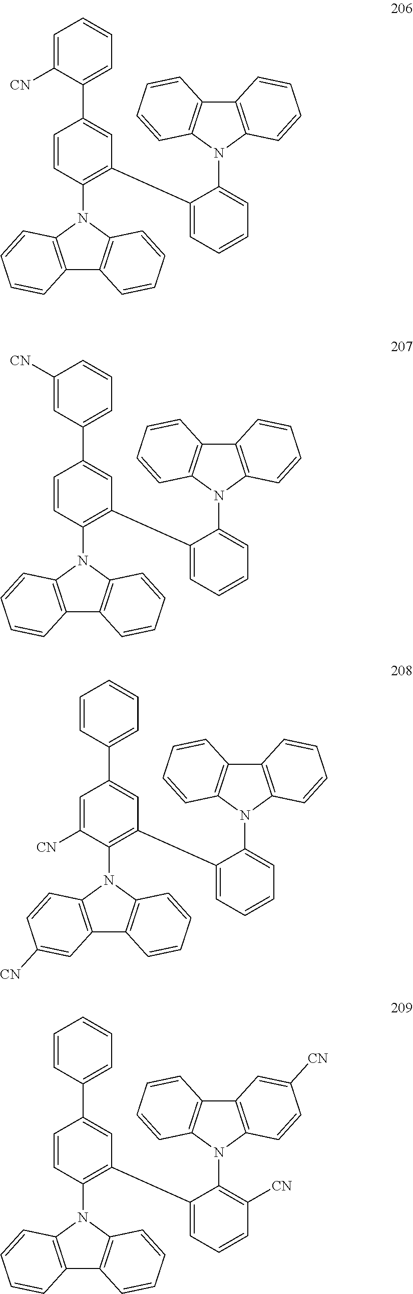

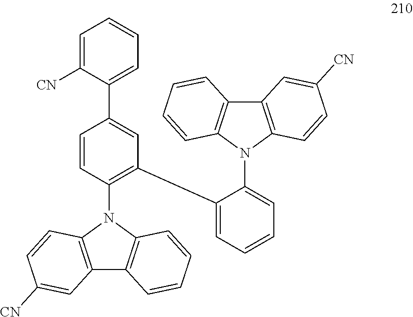

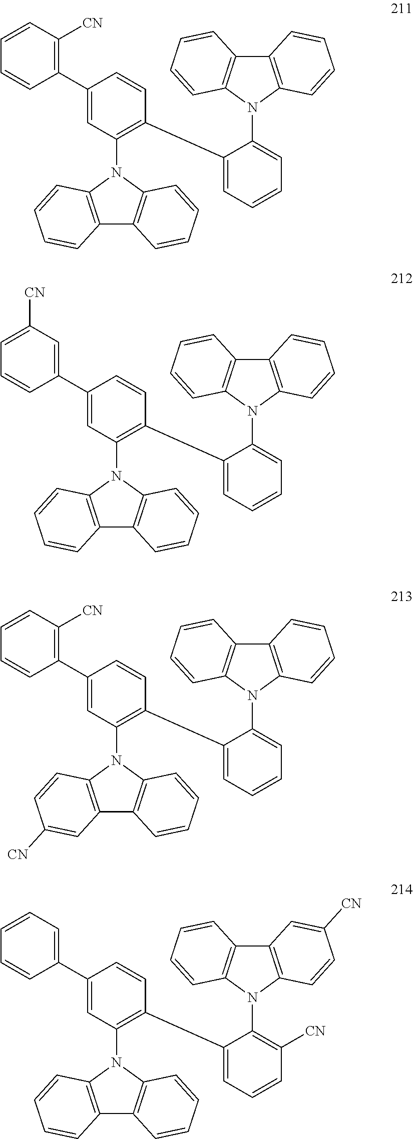

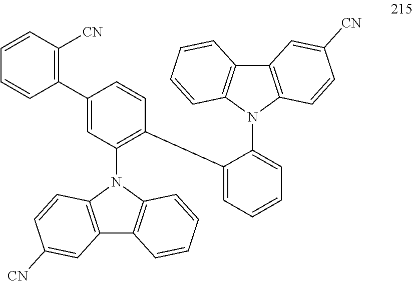

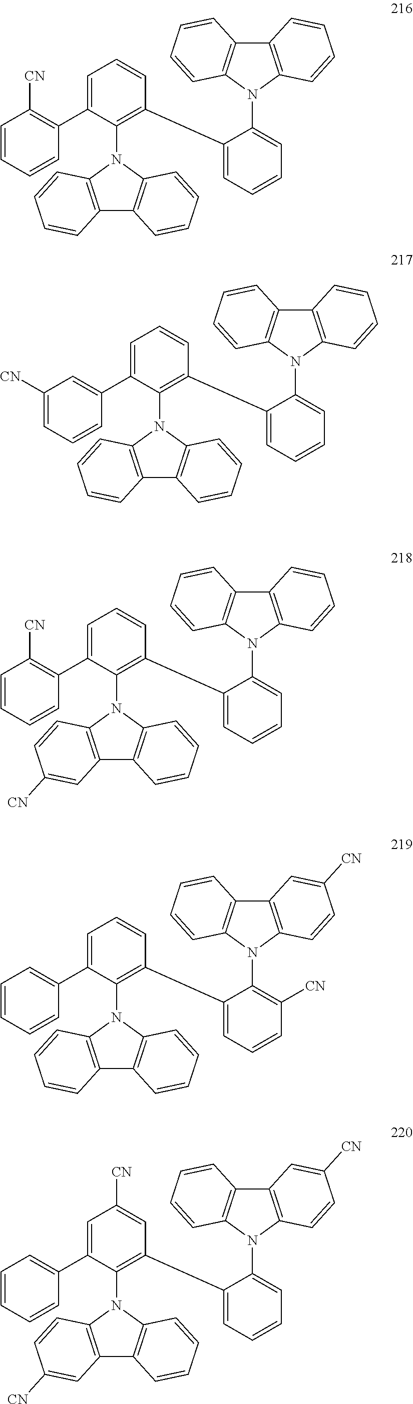

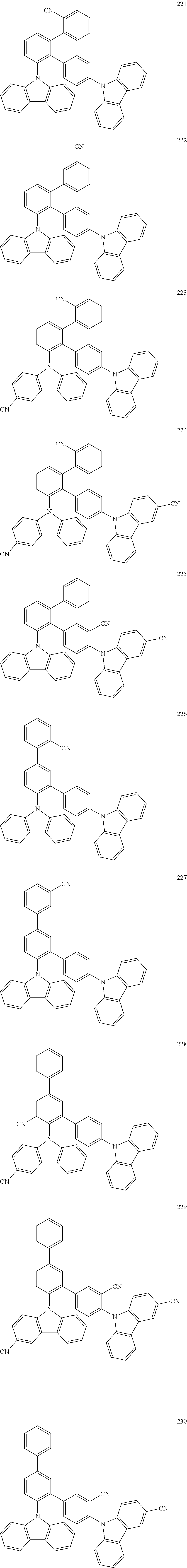

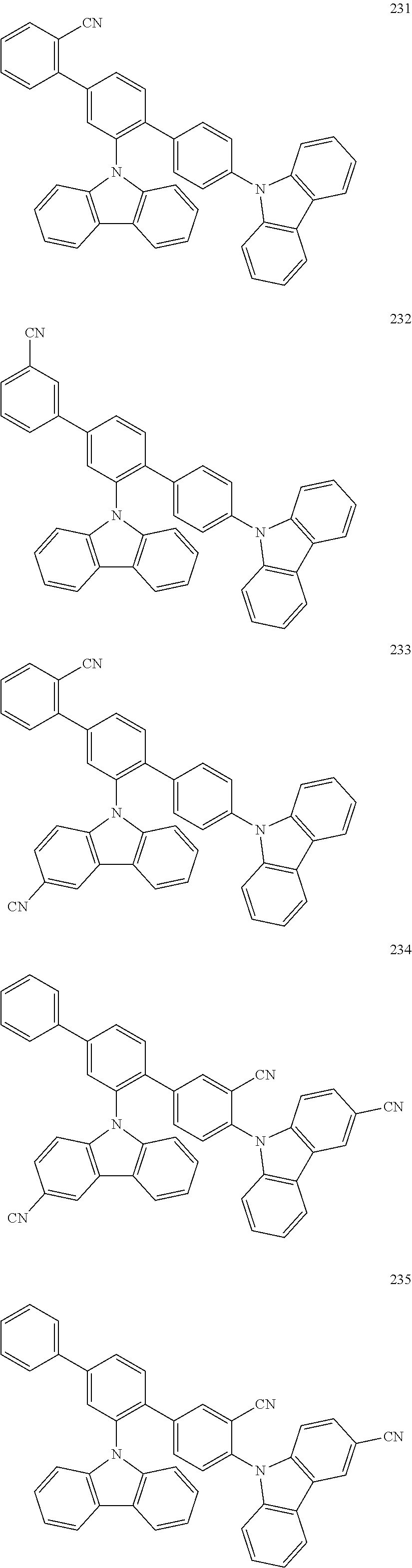

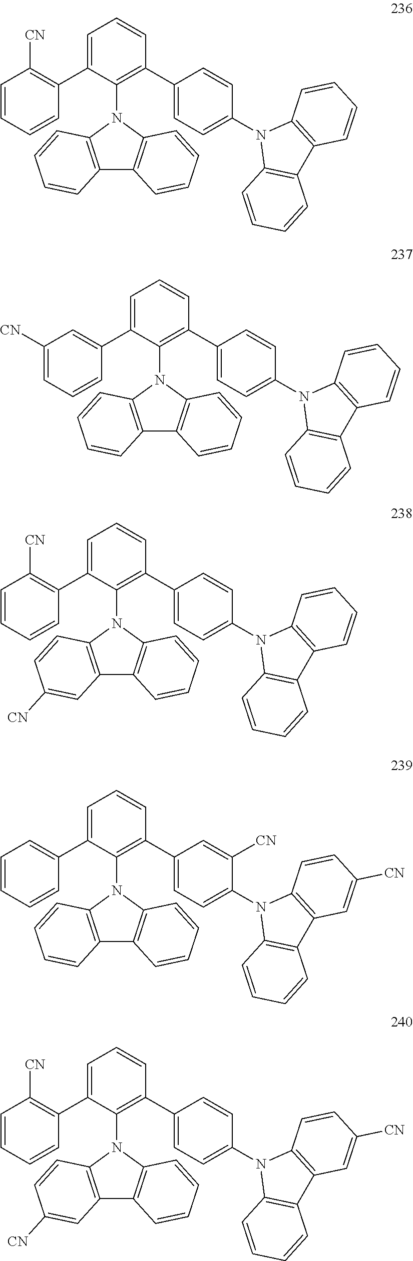

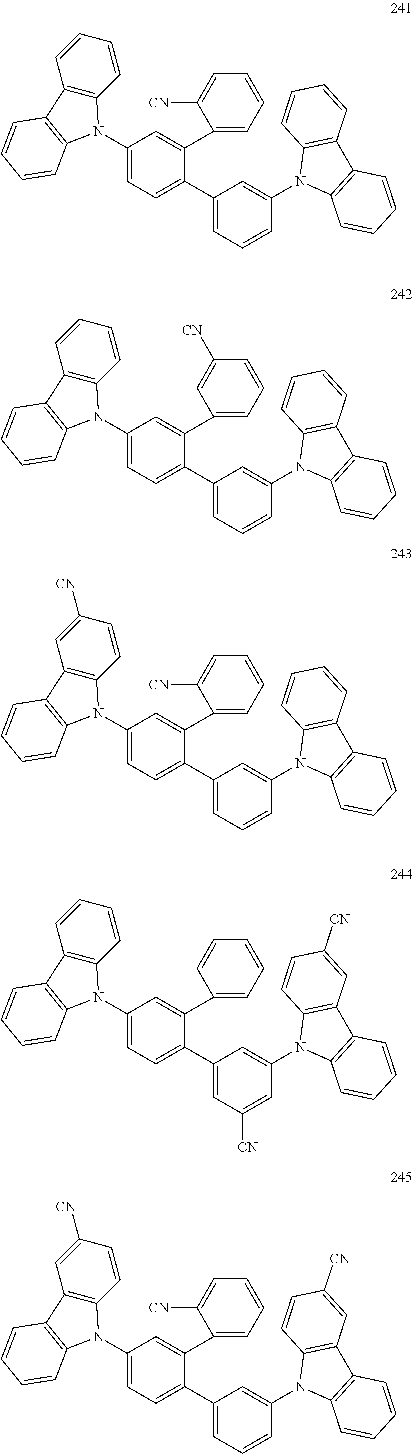

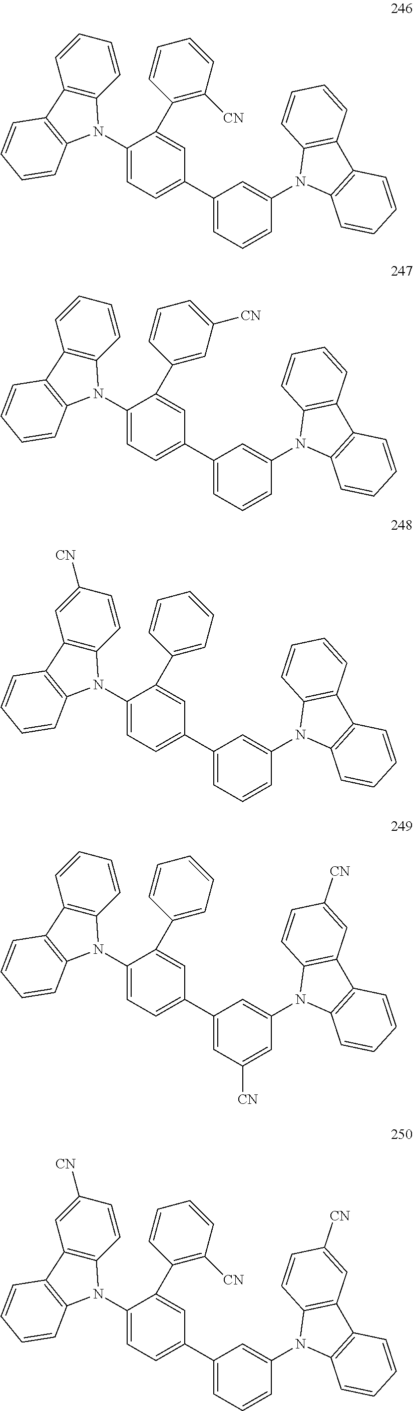

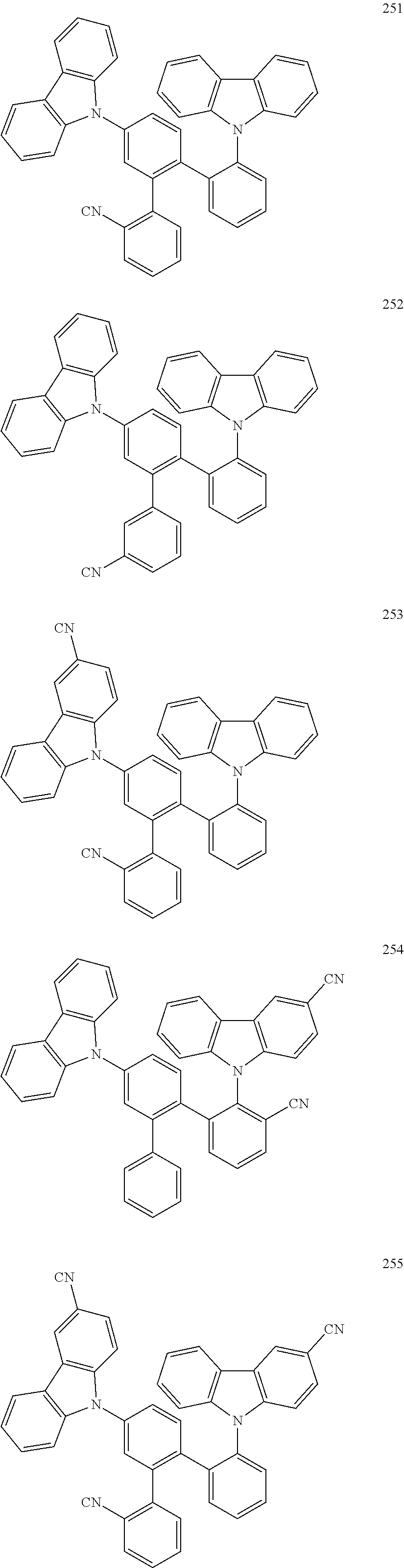

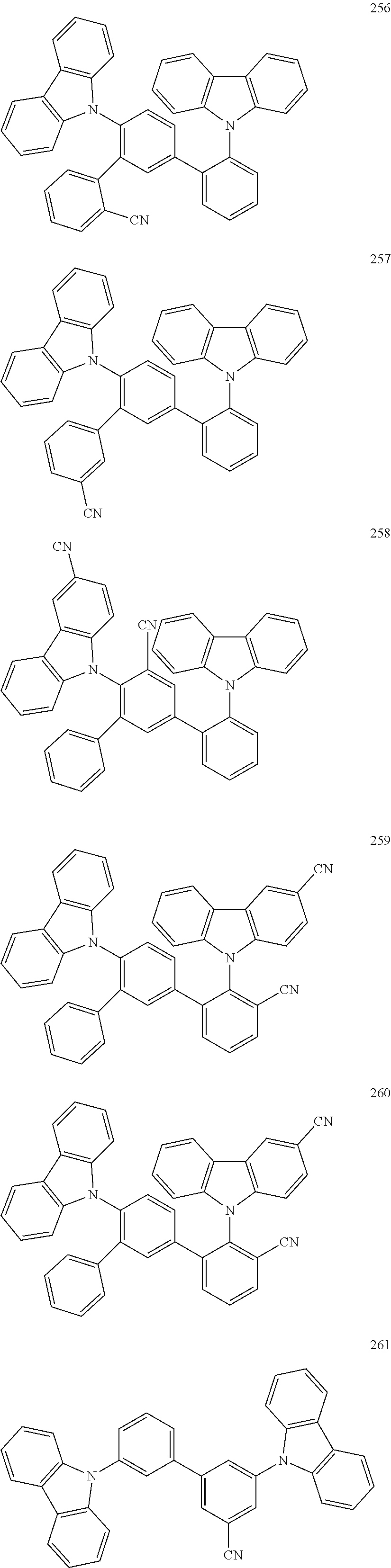

In one or more embodiments, the hole transport host may be one of Compounds H-H1 to H-H104, but embodiments of the present disclosure are not limited thereto:

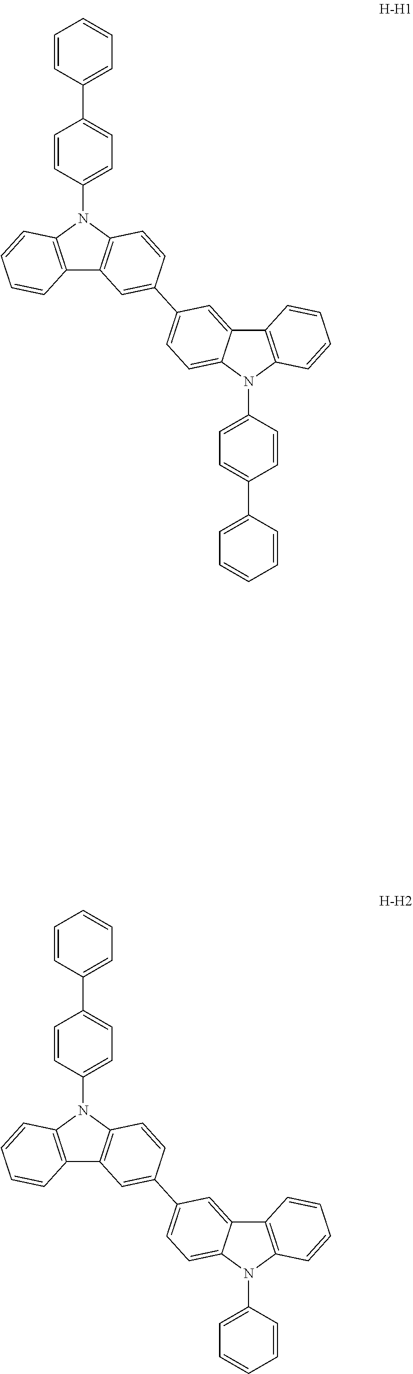 [SMILES: c1ccc(-c2ccc(-n3c4ccccc4c4cc(-c5ccc6c(c5)c5ccccc5n6-c5ccc(-c6ccccc6)cc5)ccc43)cc2)cc1 ; c1ccc(-c2ccc(-n3c4ccccc4c4cc(-c5ccc6c(c5)c5ccccc5n6-c5ccccc5)ccc43)cc2)cc1]

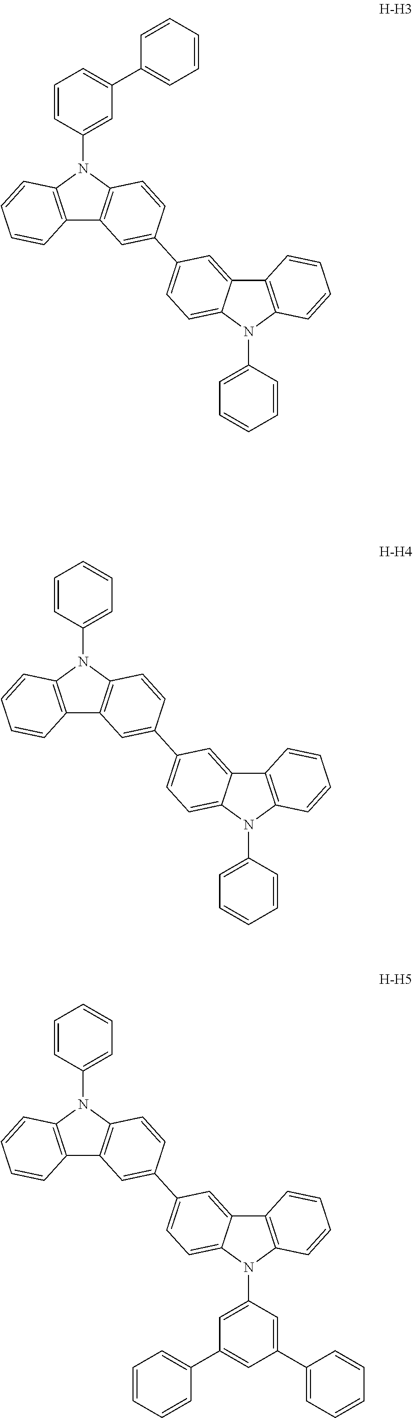 [SMILES: c1ccc(-c2cccc(-n3c4ccccc4c4cc(-c5ccc6c(c5)c5ccccc5n6-c5ccccc5)ccc43)c2)cc1 ; c1ccc(-n2c3ccccc3c3cc(-c4ccc5c(c4)c4ccccc4n5-c4ccccc4)ccc32)cc1 ; c1ccc(-c2cc(-c3ccccc3)cc(-n3c4ccccc4c4cc(-c5ccc6c(c5)c5ccccc5n6-c5ccccc5)ccc43)c2)cc1]

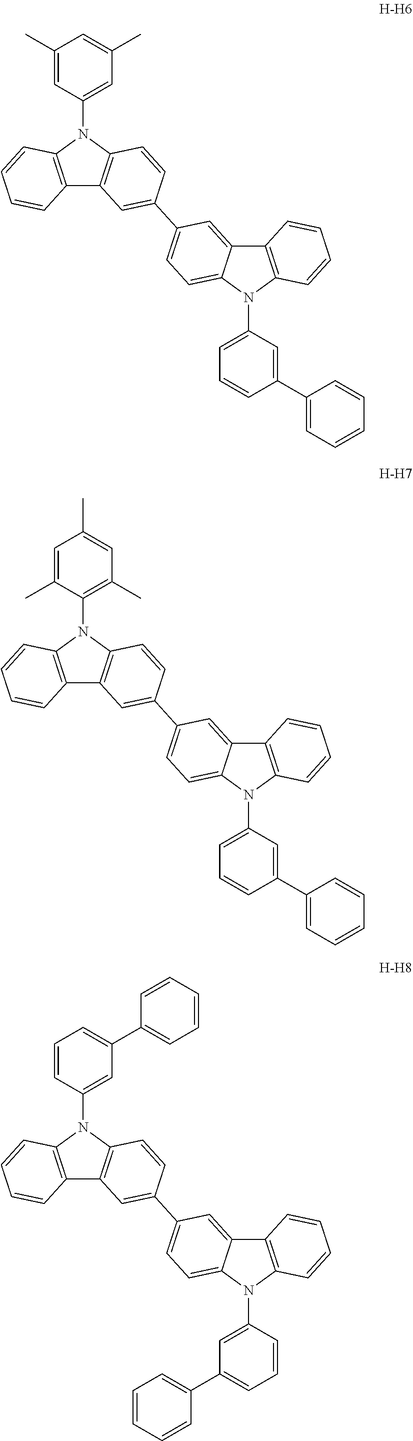 [SMILES: Cc1cc(C)cc(-n2c3ccccc3c3cc(-c4ccc5c(c4)c4ccccc4n5-c4cccc(-c5ccccc5)c4)ccc32)c1 ; Cc1cc(C)c(-n2c3ccccc3c3cc(-c4ccc5c(c4)c4ccccc4n5-c4cccc(-c5ccccc5)c4)ccc32)c(C)c1 ; c1ccc(-c2cccc(-n3c4ccccc4c4cc(-c5ccc6c(c5)c5ccccc5n6-c5cccc(-c6ccccc6)c5)ccc43)c2)cc1]

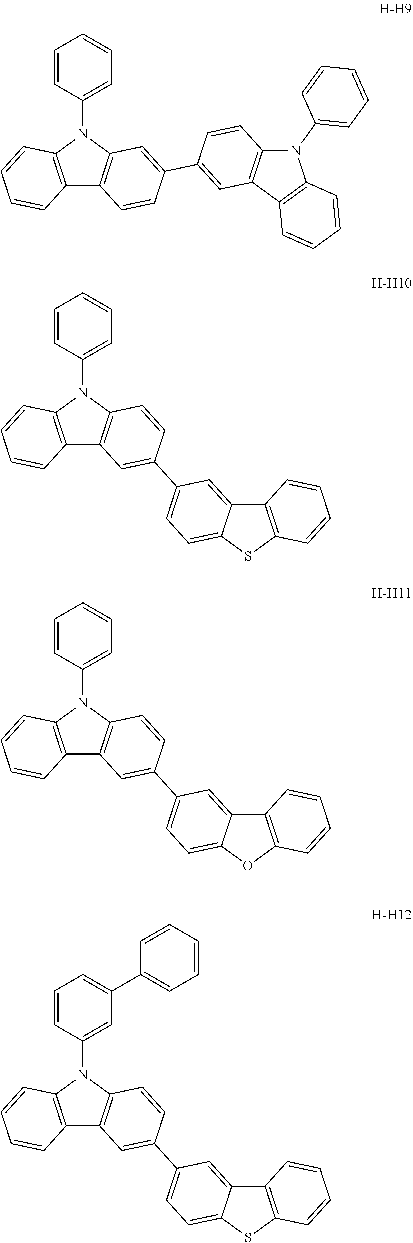 [SMILES: c1ccc(-n2c3ccccc3c3cc(-c4ccc5c6ccccc6n(-c6ccccc6)c5c4)ccc32)cc1 ; c1ccc(-n2c3ccccc3c3cc(-c4ccc5sc6ccccc6c5c4)ccc32)cc1 ; c1ccc(-n2c3ccccc3c3cc(-c4ccc5oc6ccccc6c5c4)ccc32)cc1 ; c1ccc(-c2cccc(-n3c4ccccc4c4cc(-c5ccc6sc7ccccc7c6c5)ccc43)c2)cc1]

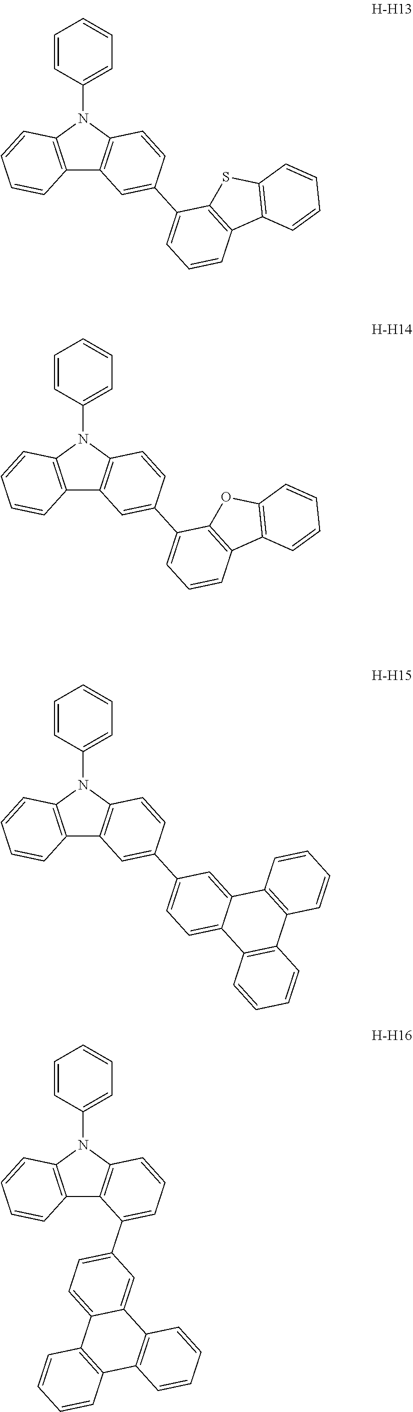 [SMILES: c1ccc(-n2c3ccccc3c3cc(-c4cccc5c4sc4ccccc45)ccc32)cc1 ; c1ccc(-n2c3ccccc3c3cc(-c4cccc5c4oc4ccccc45)ccc32)cc1 ; c1ccc(-n2c3ccccc3c3cc(-c4ccc5c6ccccc6c6ccccc6c5c4)ccc32)cc1 ; c1ccc(-n2c3ccccc3c3c(-c4ccc5c6ccccc6c6ccccc6c5c4)cccc32)cc1]

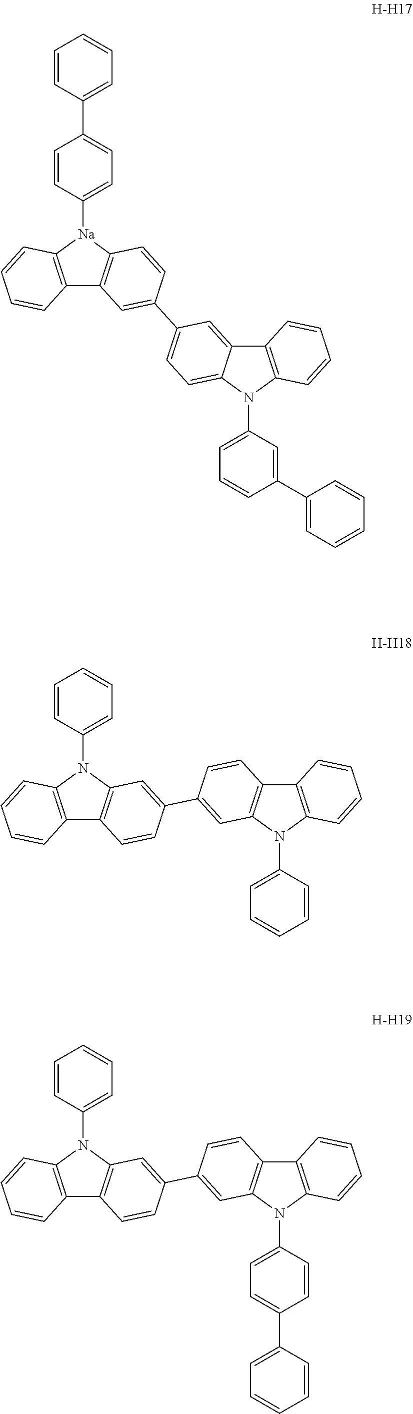

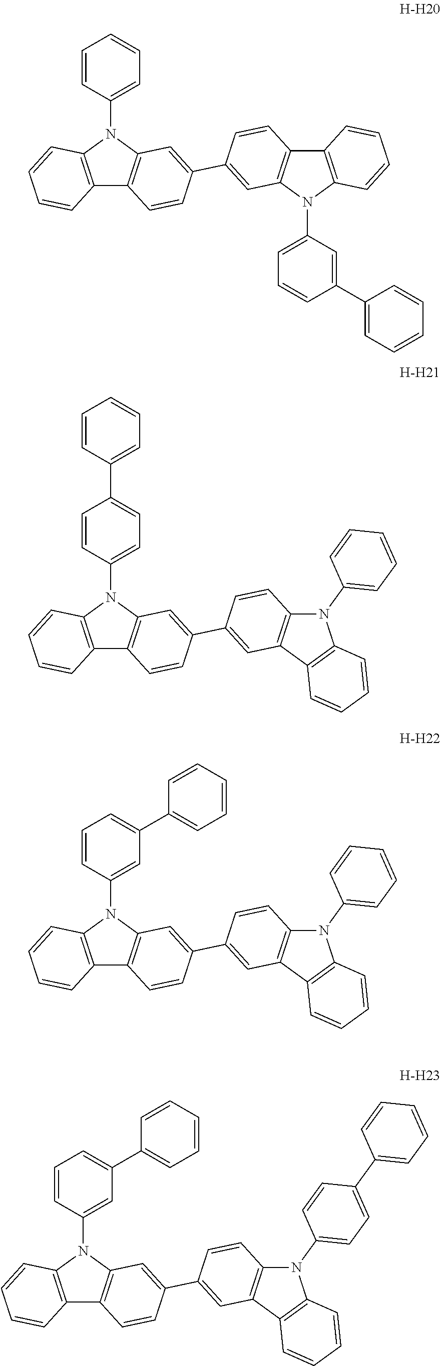 [SMILES: c1ccc(-c2cccc(-n3c4ccccc4c4ccc(-c5ccc6c7ccccc7n(-c7ccccc7)c6c5)cc43)c2)cc1 ; c1ccc(-c2ccc(-n3c4ccccc4c4ccc(-c5ccc6c(c5)c5ccccc5n6-c5ccccc5)cc43)cc2)cc1 ; c1ccc(-c2cccc(-n3c4ccccc4c4ccc(-c5ccc6c(c5)c5ccccc5n6-c5ccccc5)cc43)c2)cc1 ; c1ccc(-c2ccc(-n3c4ccccc4c4cc(-c5ccc6c7ccccc7n(-c7cccc(-c8ccccc8)c7)c6c5)ccc43)cc2)cc1]

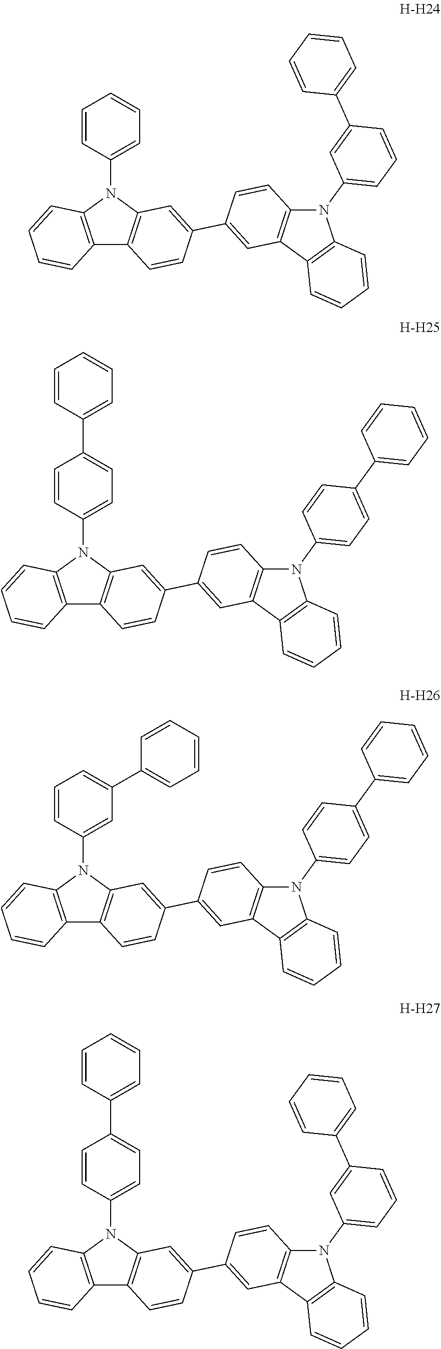 [SMILES: c1ccc(-c2cccc(-n3c4ccccc4c4cc(-c5ccc6c7ccccc7n(-c7ccccc7)c6c5)ccc43)c2)cc1 ; c1ccc(-c2ccc(-n3c4ccccc4c4cc(-c5ccc6c7ccccc7n(-c7ccc(-c8ccccc8)cc7)c6c5)ccc43)cc2)cc1 ; c1ccc(-c2ccc(-n3c4ccccc4c4cc(-c5ccc6c7ccccc7n(-c7cccc(-c8ccccc8)c7)c6c5)ccc43)cc2)cc1 ; c1ccc(-c2ccc(-n3c4ccccc4c4ccc(-c5ccc6c(c5)c5ccccc5n6-c5cccc(-c6ccccc6)c5)cc43)cc2)cc1]

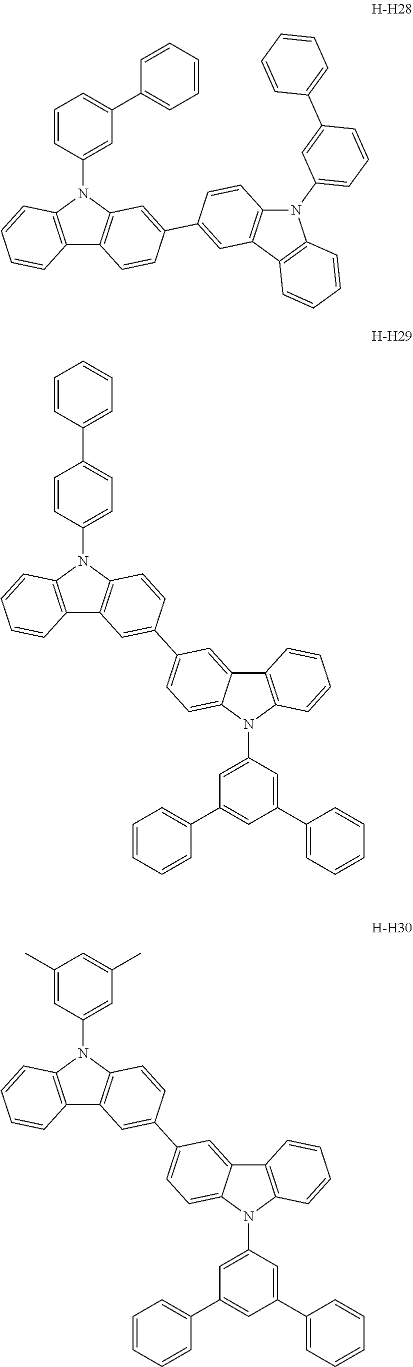 [SMILES: c1ccc(-c2cccc(-n3c4ccccc4c4cc(-c5ccc6c7ccccc7n(-c7cccc(-c8ccccc8)c7)c6c5)ccc43)c2)cc1 ; c1ccc(-c2ccc(-n3c4ccccc4c4cc(-c5ccc6c(c5)c5ccccc5n6-c5cc(-c6ccccc6)cc(-c6ccccc6)c5)ccc43)cc2)cc1 ; Cc1cc(C)cc(-n2c3ccccc3c3cc(-c4ccc5c(c4)c4ccccc4n5-c4cc(-c5ccccc5)cc(-c5ccccc5)c4)ccc32)c1]

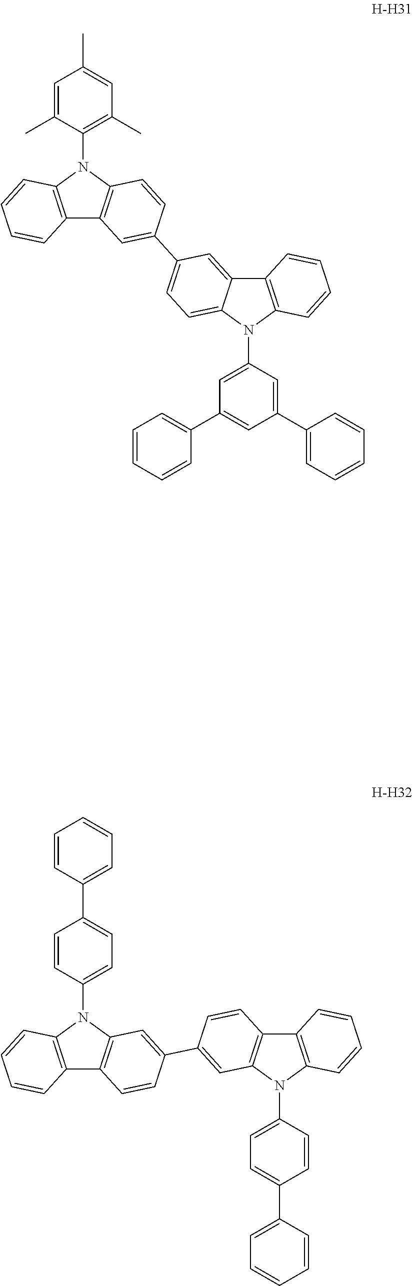 [SMILES: Cc1cc(C)c(-n2c3ccccc3c3cc(-c4ccc5c(c4)c4ccccc4n5-c4cc(-c5ccccc5)cc(-c5ccccc5)c4)ccc32)c(C)c1 ; c1ccc(-c2ccc(-n3c4ccccc4c4ccc(-c5ccc6c7ccccc7n(-c7ccc(-c8ccccc8)cc7)c6c5)cc43)cc2)cc1]

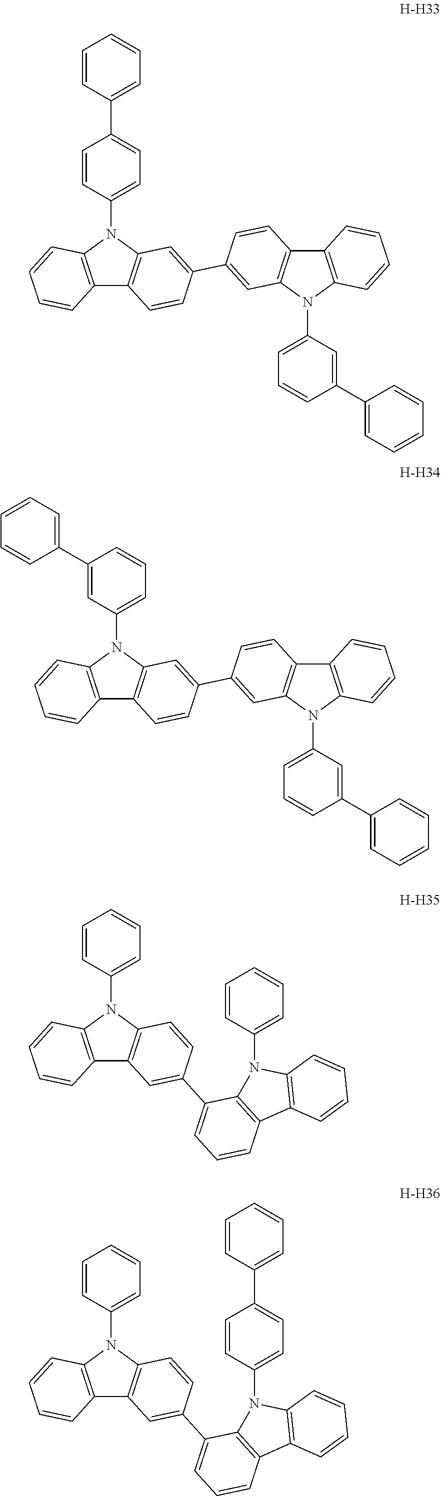 [SMILES: c1ccc(-c2ccc(-n3c4ccccc4c4ccc(-c5ccc6c7ccccc7n(-c7cccc(-c8ccccc8)c7)c6c5)cc43)cc2)cc1 ; c1ccc(-c2cccc(-n3c4ccccc4c4ccc(-c5ccc6c7ccccc7n(-c7cccc(-c8ccccc8)c7)c6c5)cc43)c2)cc1 ; c1ccc(-n2c3ccccc3c3cc(-c4cccc5c6ccccc6n(-c6ccccc6)c45)ccc32)cc1 ; c1ccc(-c2ccc(-n3c4ccccc4c4cccc(-c5ccc6c(c5)c5ccccc5n6-c5ccccc5)c43)cc2)cc1]

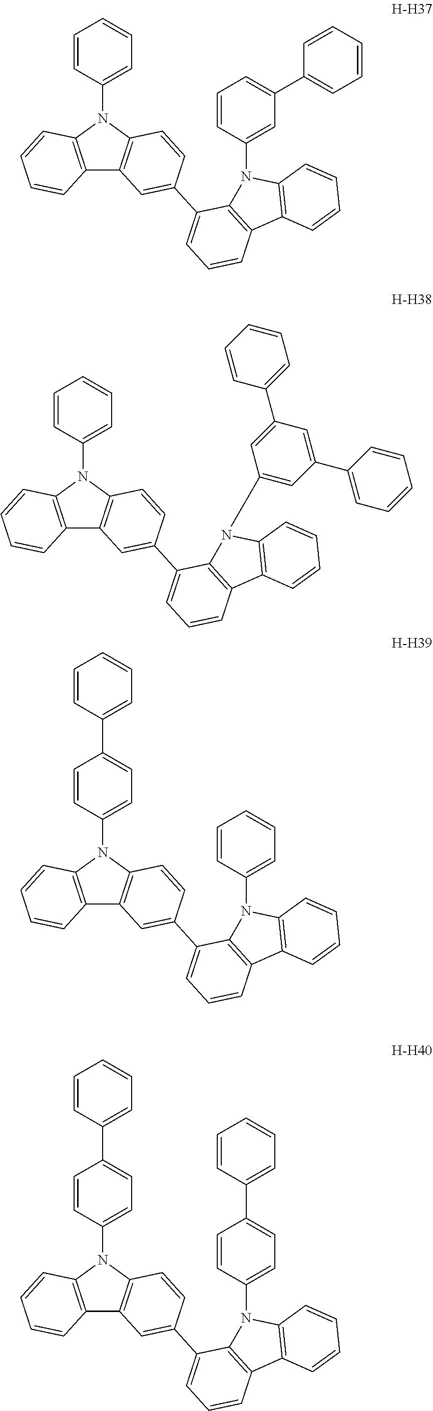 [SMILES: c1ccc(-c2cccc(-n3c4ccccc4c4cccc(-c5ccc6c(c5)c5ccccc5n6-c5ccccc5)c43)c2)cc1 ; c1ccc(-c2cc(-c3ccccc3)cc(-n3c4ccccc4c4cccc(-c5ccc6c(c5)c5ccccc5n6-c5ccccc5)c43)c2)cc1 ; c1ccc(-c2ccc(-n3c4ccccc4c4cc(-c5cccc6c7ccccc7n(-c7ccccc7)c56)ccc43)cc2)cc1 ; c1ccc(-c2ccc(-n3c4ccccc4c4cc(-c5cccc6c7ccccc7n(-c7ccc(-c8ccccc8)cc7)c56)ccc43)cc2)cc1]

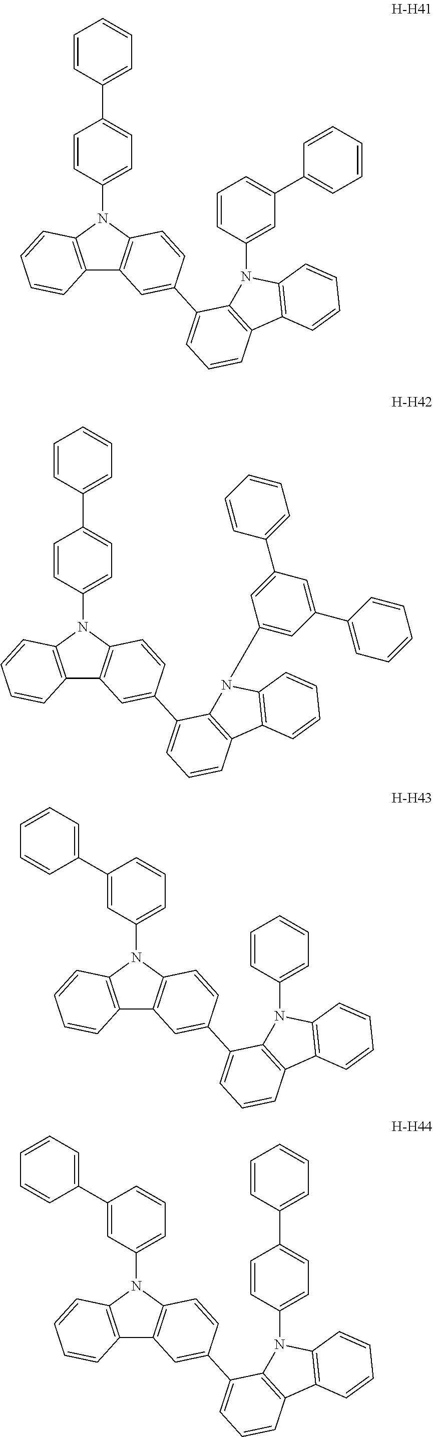

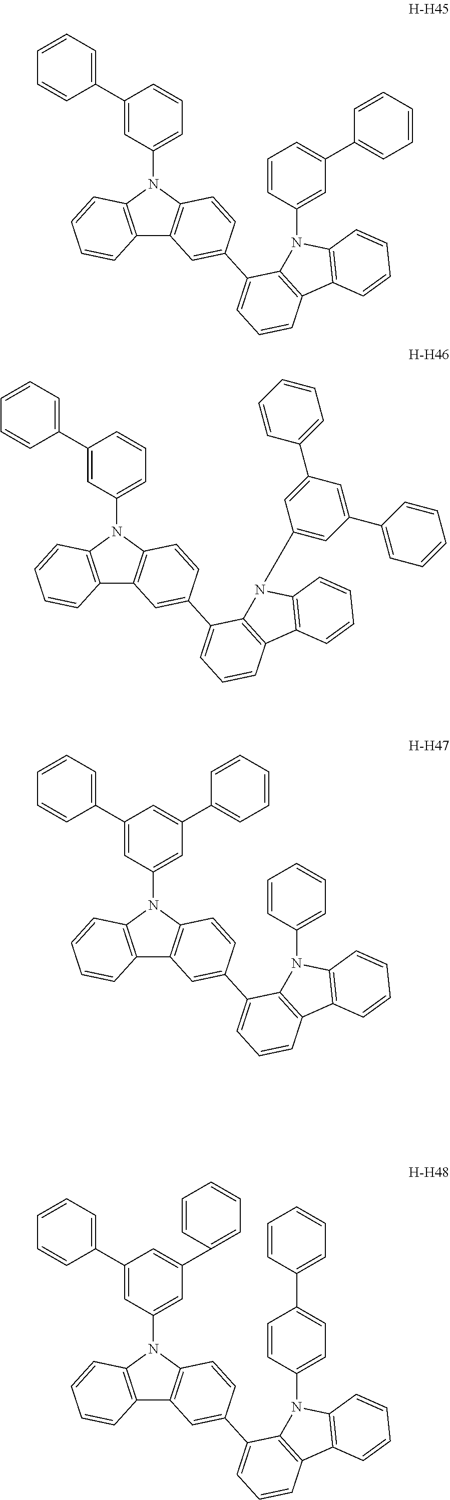 [SMILES: c1ccc(-c2cccc(-n3c4ccccc4c4cc(-c5cccc6c7ccccc7n(-c7cccc(-c8ccccc8)c7)c56)ccc43)c2)cc1 ; c1ccc(-c2cccc(-n3c4ccccc4c4cc(-c5cccc6c7ccccc7n(-c7cc(-c8ccccc8)cc(-c8ccccc8)c7)c56)ccc43)c2)cc1 ; c1ccc(-c2cc(-c3ccccc3)cc(-n3c4ccccc4c4cc(-c5cccc6c7ccccc7n(-c7ccccc7)c56)ccc43)c2)cc1 ; c1ccc(-c2ccc(-n3c4ccccc4c4cccc(-c5ccc6c(c5)c5ccccc5n6-c5cc(-c6ccccc6)cc(-c6ccccc6)c5)c43)cc2)cc1]

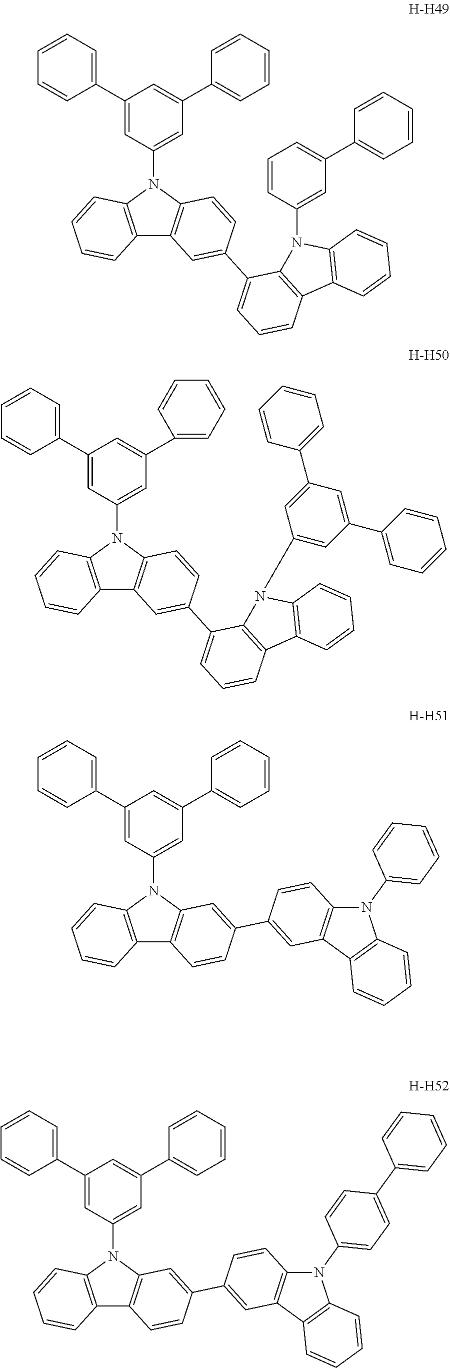 [SMILES: c1ccc(-c2cc(-c3ccccc3)cc(-n3c4ccccc4c4cc(-c5cccc6c7ccccc7n(-c7cccc(-c8ccccc8)c7)c56)ccc43)c2)cc1 ; c1ccc(-c2cc(-c3ccccc3)cc(-n3c4ccccc4c4cc(-c5cccc6c7ccccc7n(-c7cc(-c8ccccc8)cc(-c8ccccc8)c7)c56)ccc43)c2)cc1 ; c1ccc(-c2cc(-c3ccccc3)cc(-n3c4ccccc4c4ccc(-c5ccc6c(c5)c5ccccc5n6-c5ccccc5)cc43)c2)cc1 ; c1ccc(-c2ccc(-n3c4ccccc4c4cc(-c5ccc6c7ccccc7n(-c7cc(-c8ccccc8)cc(-c8ccccc8)c7)c6c5)ccc43)cc2)cc1]

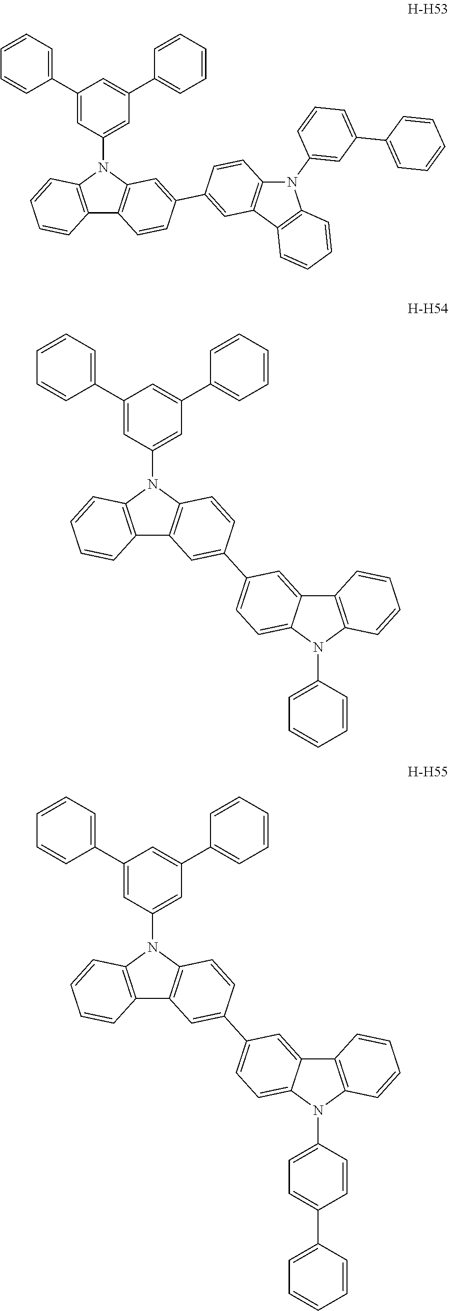 [SMILES: c1ccc(-c2cccc(-n3c4ccccc4c4cc(-c5ccc6c7ccccc7n(-c7cc(-c8ccccc8)cc(-c8ccccc8)c7)c6c5)ccc43)c2)cc1 ; c1ccc(-c2cc(-c3ccccc3)cc(-n3c4ccccc4c4cc(-c5ccc6c(c5)c5ccccc5n6-c5ccccc5)ccc43)c2)cc1 ; c1ccc(-c2ccc(-n3c4ccccc4c4cc(-c5ccc6c(c5)c5ccccc5n6-c5cc(-c6ccccc6)cc(-c6ccccc6)c5)ccc43)cc2)cc1]

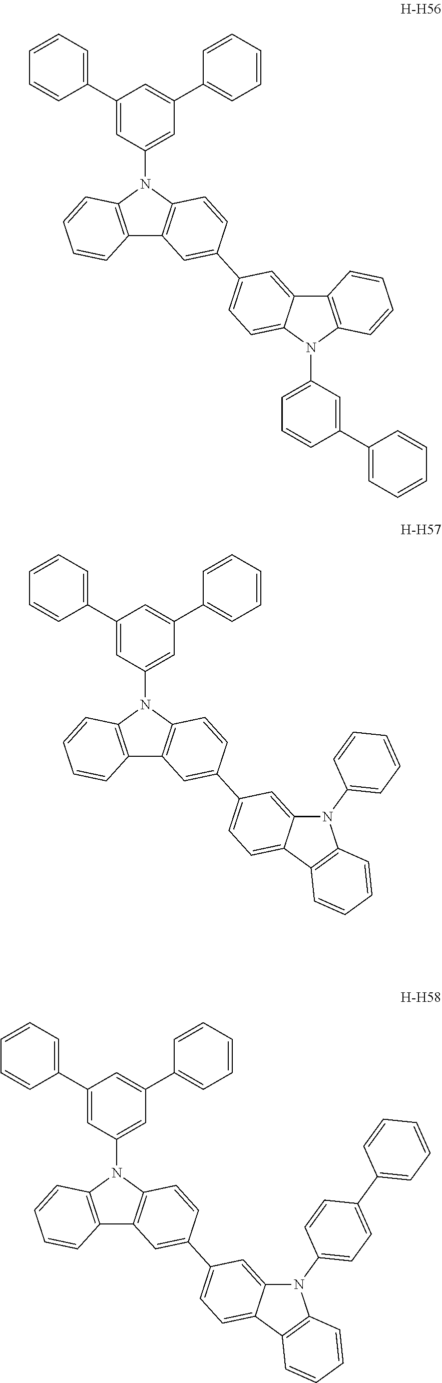 [SMILES: c1ccc(-c2cccc(-n3c4ccccc4c4cc(-c5ccc6c(c5)c5ccccc5n6-c5cc(-c6ccccc6)cc(-c6ccccc6)c5)ccc43)c2)cc1 ; c1ccc(-c2cc(-c3ccccc3)cc(-n3c4ccccc4c4cc(-c5ccc6c7ccccc7n(-c7ccccc7)c6c5)ccc43)c2)cc1 ; c1ccc(-c2ccc(-n3c4ccccc4c4ccc(-c5ccc6c(c5)c5ccccc5n6-c5cc(-c6ccccc6)cc(-c6ccccc6)c5)cc43)cc2)cc1]

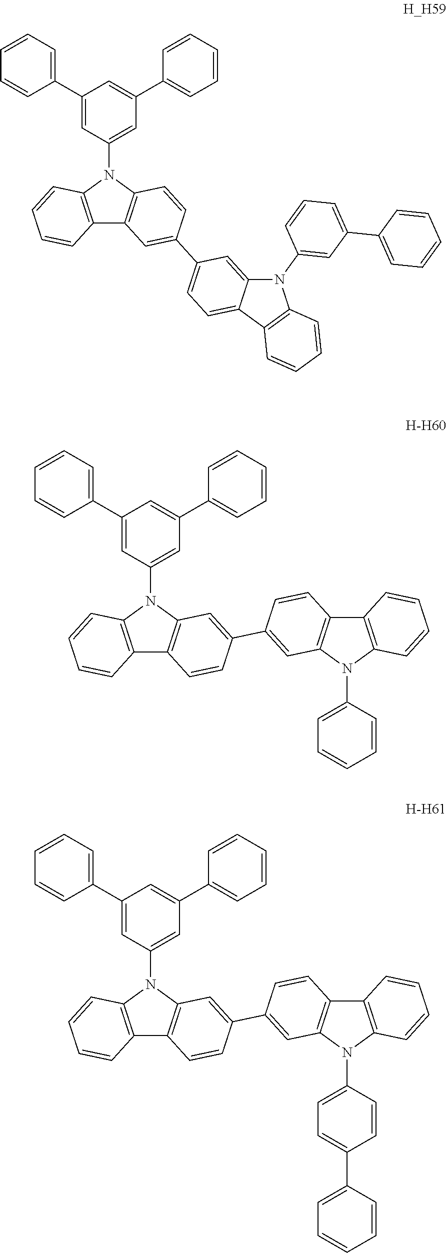 [SMILES: c1ccc(-c2cccc(-n3c4ccccc4c4ccc(-c5ccc6c(c5)c5ccccc5n6-c5cc(-c6ccccc6)cc(-c6ccccc6)c5)cc43)c2)cc1 ; c1ccc(-c2cc(-c3ccccc3)cc(-n3c4ccccc4c4ccc(-c5ccc6c7ccccc7n(-c7ccccc7)c6c5)cc43)c2)cc1 ; c1ccc(-c2ccc(-n3c4ccccc4c4ccc(-c5ccc6c7ccccc7n(-c7cc(-c8ccccc8)cc(-c8ccccc8)c7)c6c5)cc43)cc2)cc1]

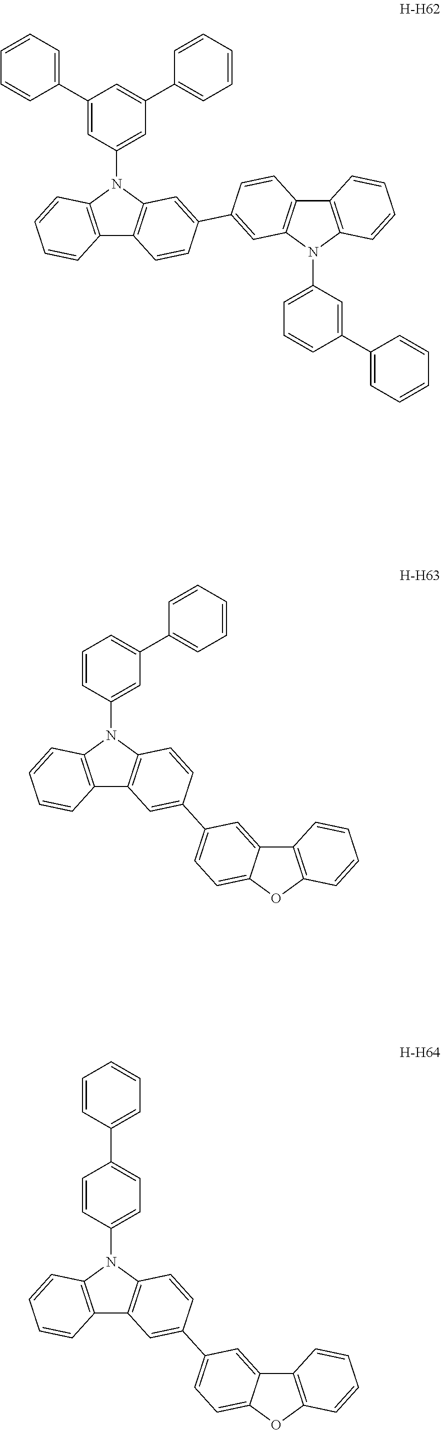 [SMILES: c1ccc(-c2cccc(-n3c4ccccc4c4ccc(-c5ccc6c7ccccc7n(-c7cc(-c8ccccc8)cc(-c8ccccc8)c7)c6c5)cc43)c2)cc1 ; c1ccc(-c2cccc(-n3c4ccccc4c4cc(-c5ccc6oc7ccccc7c6c5)ccc43)c2)cc1 ; c1ccc(-c2ccc(-n3c4ccccc4c4cc(-c5ccc6oc7ccccc7c6c5)ccc43)cc2)cc1]

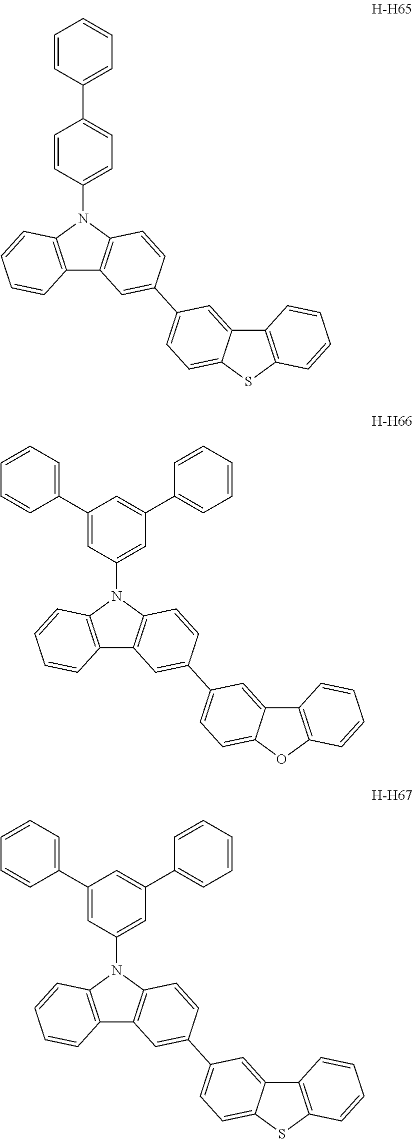 [SMILES: c1ccc(-c2ccc(-n3c4ccccc4c4cc(-c5ccc6sc7ccccc7c6c5)ccc43)cc2)cc1 ; c1ccc(-c2cc(-c3ccccc3)cc(-n3c4ccccc4c4cc(-c5ccc6oc7ccccc7c6c5)ccc43)c2)cc1 ; c1ccc(-c2cc(-c3ccccc3)cc(-n3c4ccccc4c4cc(-c5ccc6sc7ccccc7c6c5)ccc43)c2)cc1]

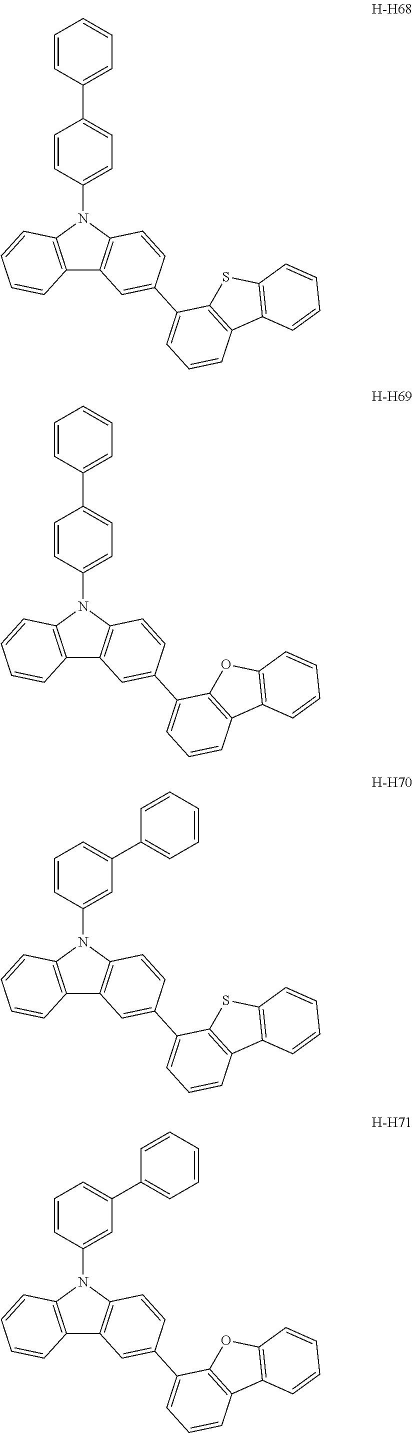

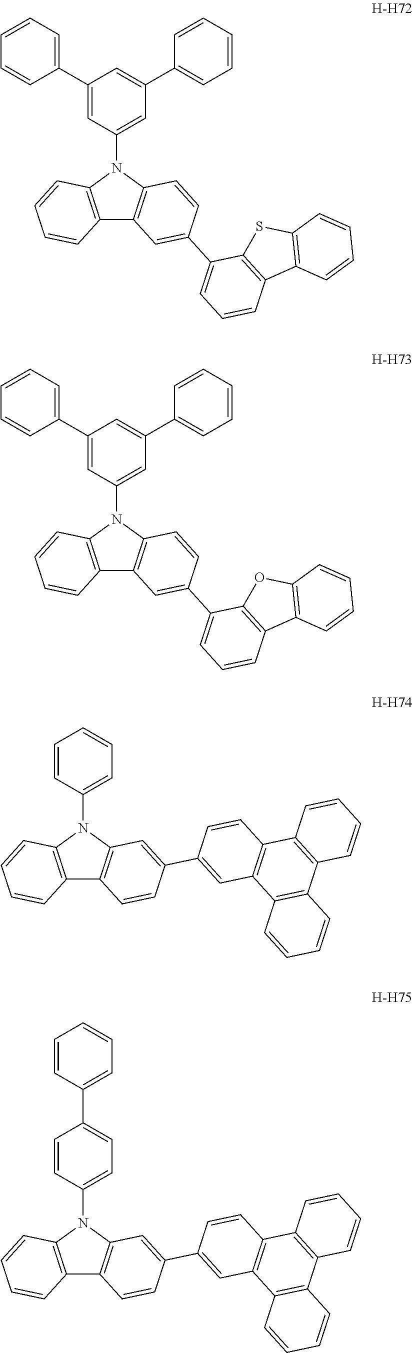 [SMILES: c1ccc(-c2cc(-c3ccccc3)cc(-n3c4ccccc4c4cc(-c5cccc6c5sc5ccccc56)ccc43)c2)cc1 ; c1ccc(-c2cc(-c3ccccc3)cc(-n3c4ccccc4c4cc(-c5cccc6c5oc5ccccc56)ccc43)c2)cc1 ; c1ccc(-n2c3ccccc3c3ccc(-c4ccc5c6ccccc6c6ccccc6c5c4)cc32)cc1 ; c1ccc(-c2ccc(-n3c4ccccc4c4ccc(-c5ccc6c7ccccc7c7ccccc7c6c5)cc43)cc2)cc1]

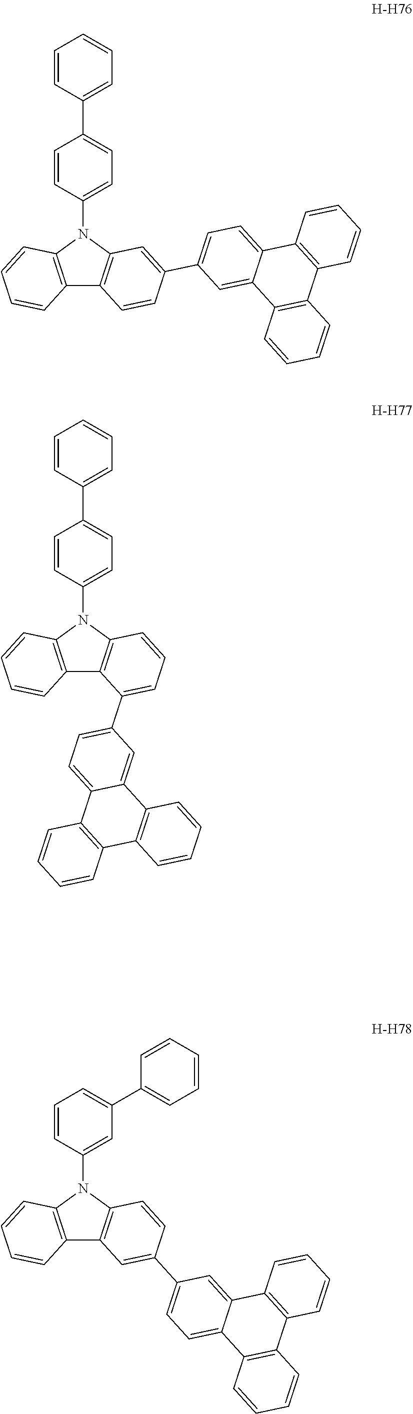 [SMILES: c1ccc(-c2ccc(-n3c4ccccc4c4ccc(-c5ccc6c7ccccc7c7ccccc7c6c5)cc43)cc2)cc1 ; c1ccc(-c2ccc(-n3c4ccccc4c4c(-c5ccc6c7ccccc7c7ccccc7c6c5)cccc43)cc2)cc1 ; c1ccc(-c2cccc(-n3c4ccccc4c4cc(-c5ccc6c7ccccc7c7ccccc7c6c5)ccc43)c2)cc1]

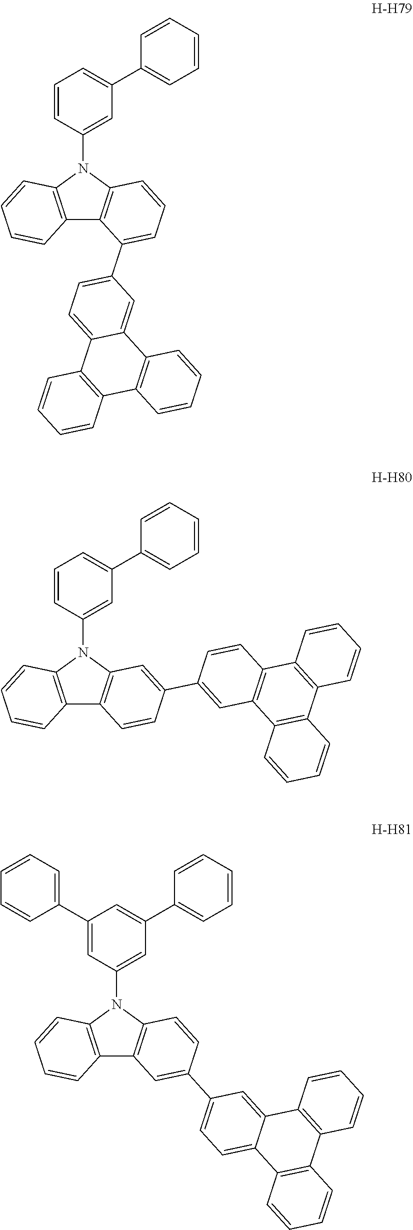 [SMILES: c1ccc(-c2cccc(-n3c4ccccc4c4c(-c5ccc6c7ccccc7c7ccccc7c6c5)cccc43)c2)cc1 ; c1ccc(-c2cccc(-n3c4ccccc4c4ccc(-c5ccc6c7ccccc7c7ccccc7c6c5)cc43)c2)cc1 ; c1ccc(-c2cc(-c3ccccc3)cc(-n3c4ccccc4c4cc(-c5ccc6c7ccccc7c7ccccc7c6c5)ccc43)c2)cc1]

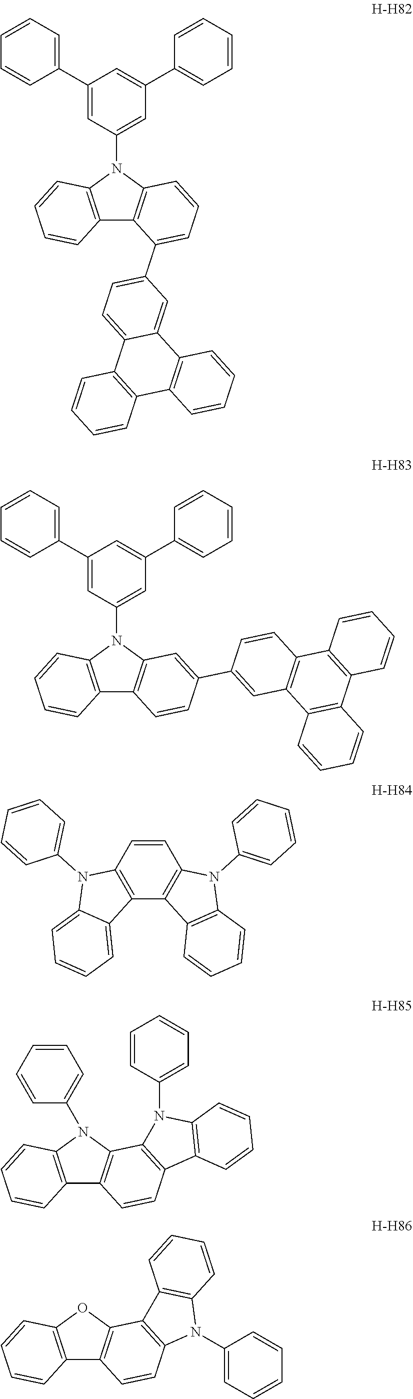

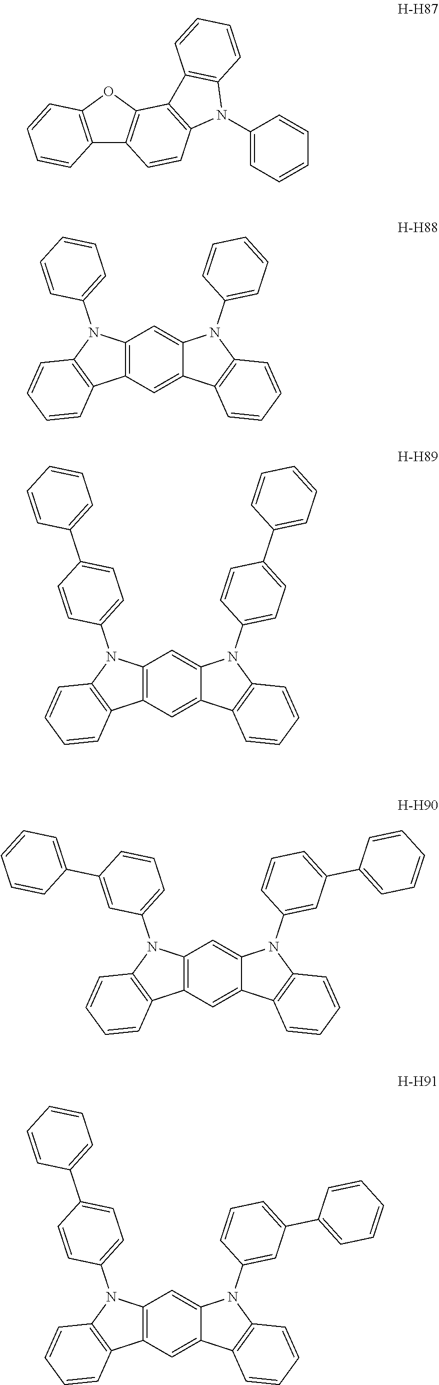

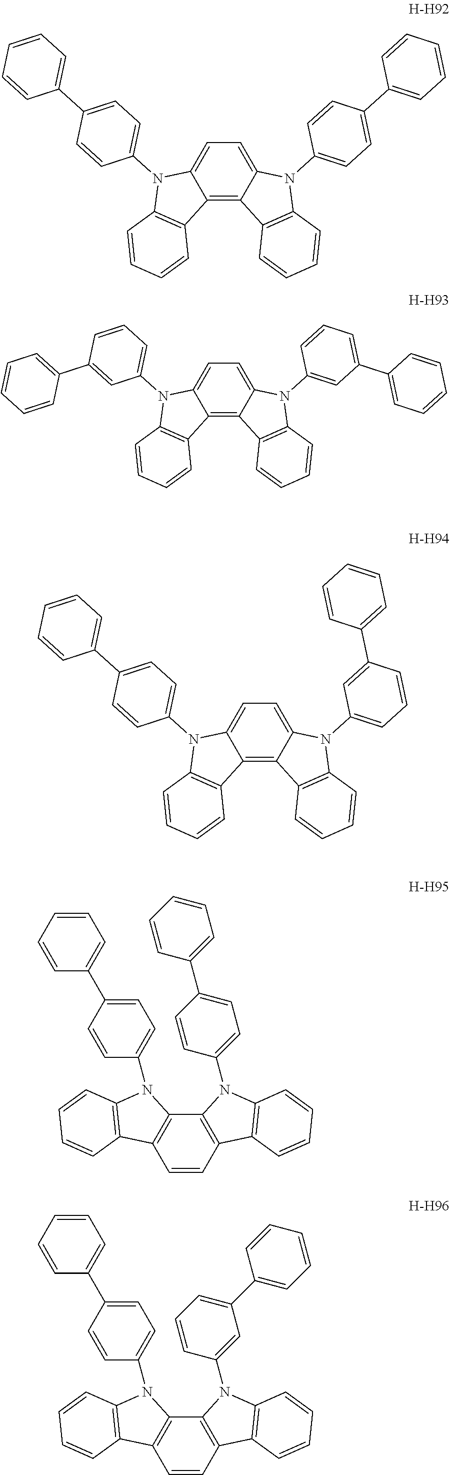 [SMILES: c1ccc(-c2ccc(-n3c4ccccc4c4c5c6ccccc6n(-c6ccc(-c7ccccc7)cc6)c5ccc43)cc2)cc1 ; c1ccc(-c2cccc(-n3c4ccccc4c4c5c6ccccc6n(-c6cccc(-c7ccccc7)c6)c5ccc43)c2)cc1 ; c1ccc(-c2ccc(-n3c4ccccc4c4c5c6ccccc6n(-c6cccc(-c7ccccc7)c6)c5ccc43)cc2)cc1 ; c1ccc(-c2ccc(-n3c4ccccc4c4ccc5c6ccccc6n(-c6ccc(-c7ccccc7)cc6)c5c43)cc2)cc1 ; c1ccc(-c2ccc(-n3c4ccccc4c4ccc5c6ccccc6n(-c6cccc(-c7ccccc7)c6)c5c43)cc2)cc1]

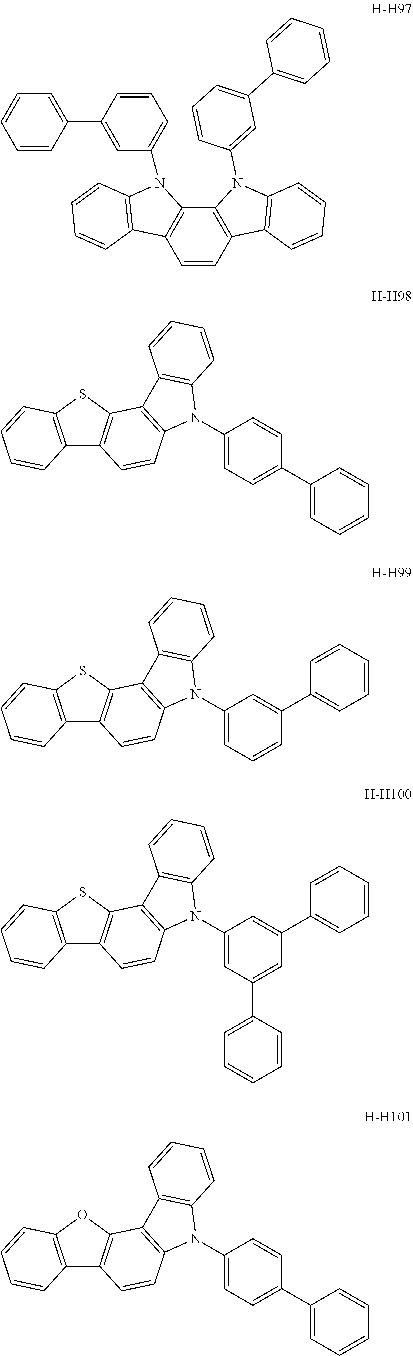 [SMILES: c1ccc(-c2cccc(-n3c4ccccc4c4ccc5c6ccccc6n(-c6cccc(-c7ccccc7)c6)c5c43)c2)cc1 ; c1ccc(-c2ccc(-n3c4ccccc4c4c5sc6ccccc6c5ccc43)cc2)cc1 ; c1ccc(-c2cccc(-n3c4ccccc4c4c5sc6ccccc6c5ccc43)c2)cc1 ; c1ccc(-c2cc(-c3ccccc3)cc(-n3c4ccccc4c4c5sc6ccccc6c5ccc43)c2)cc1 ; c1ccc(-c2ccc(-n3c4ccccc4c4c5oc6ccccc6c5ccc43)cc2)cc1]

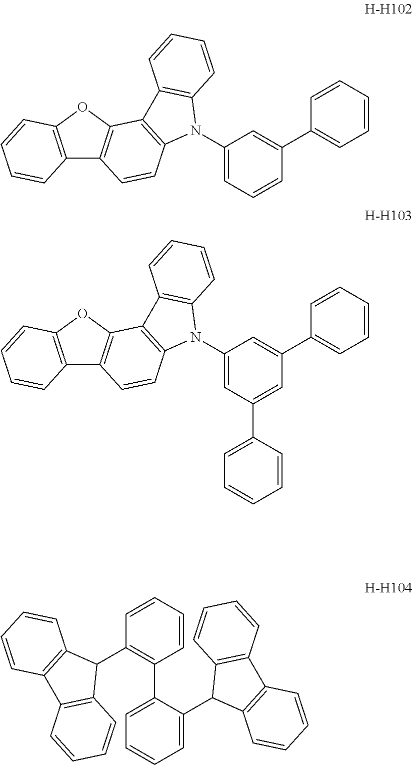

In one or more embodiments, the bipolar host may be from Group HEH1, but embodiments of the present disclosure are not limited thereto:

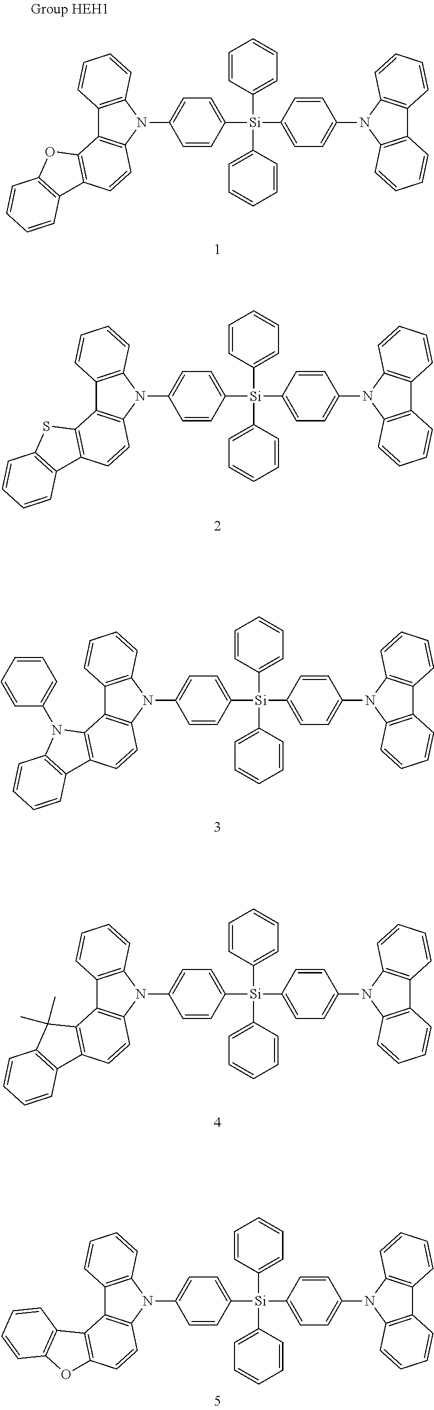

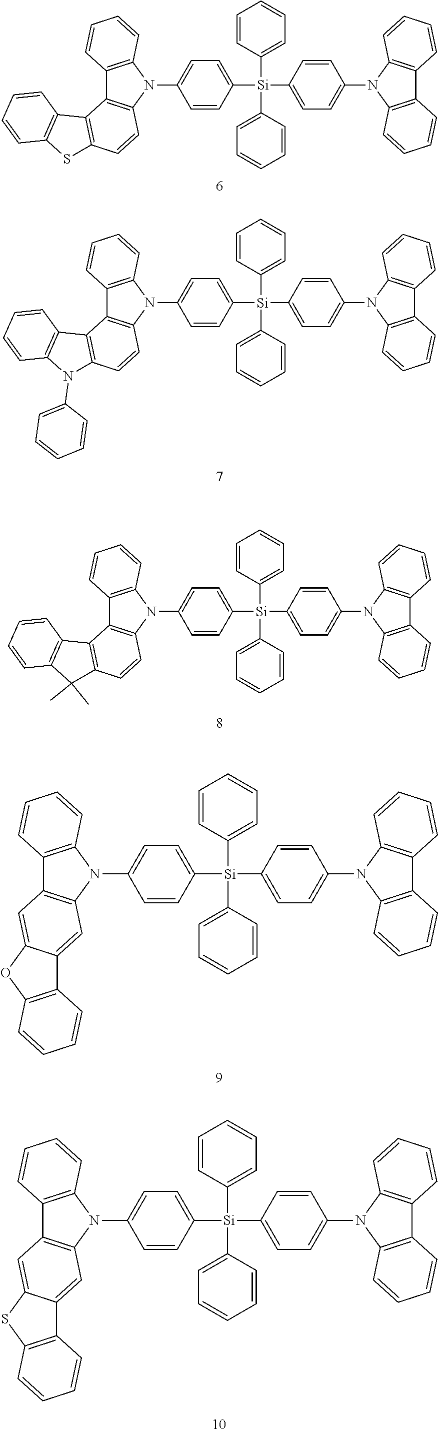

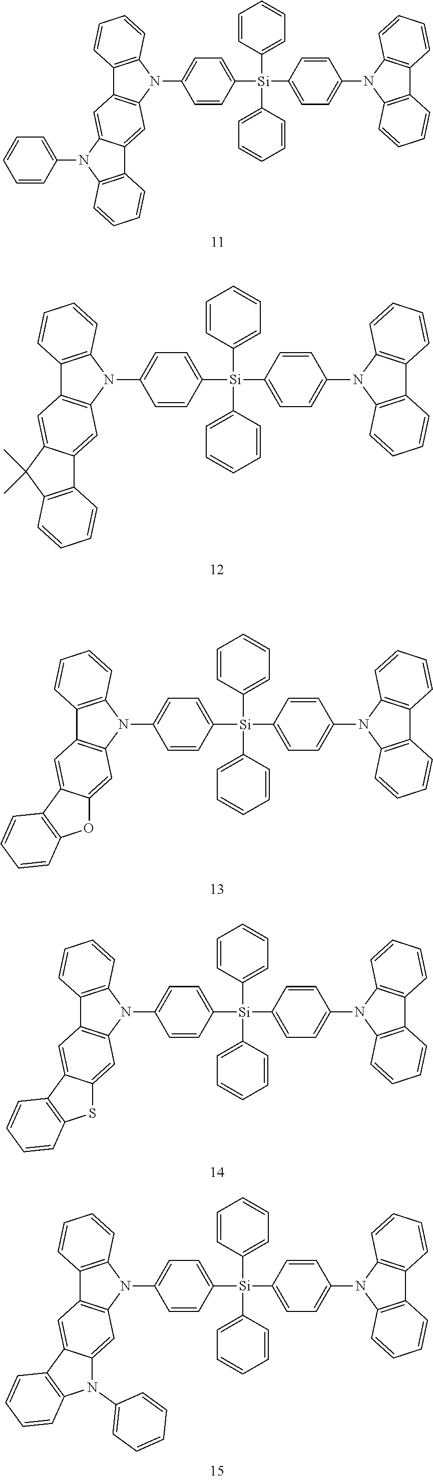

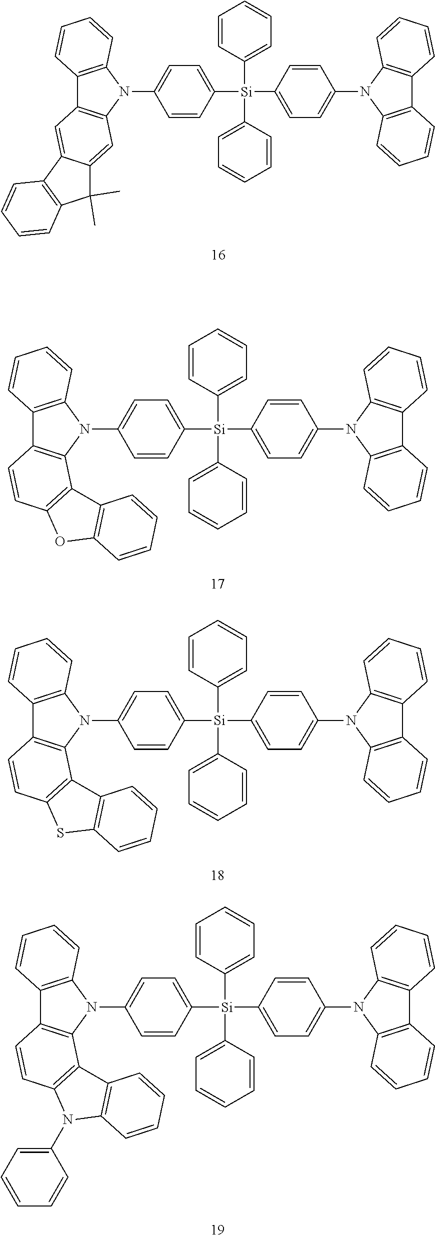

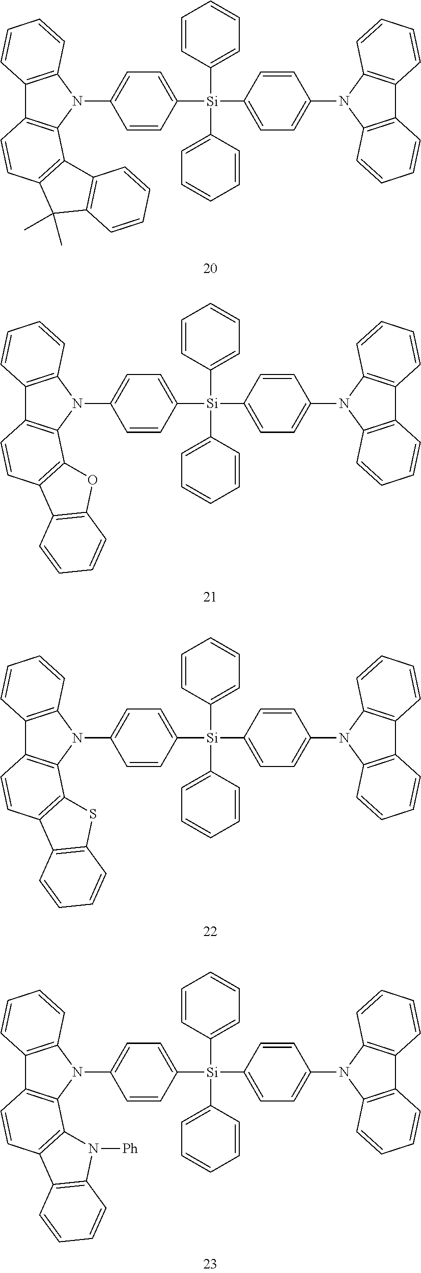

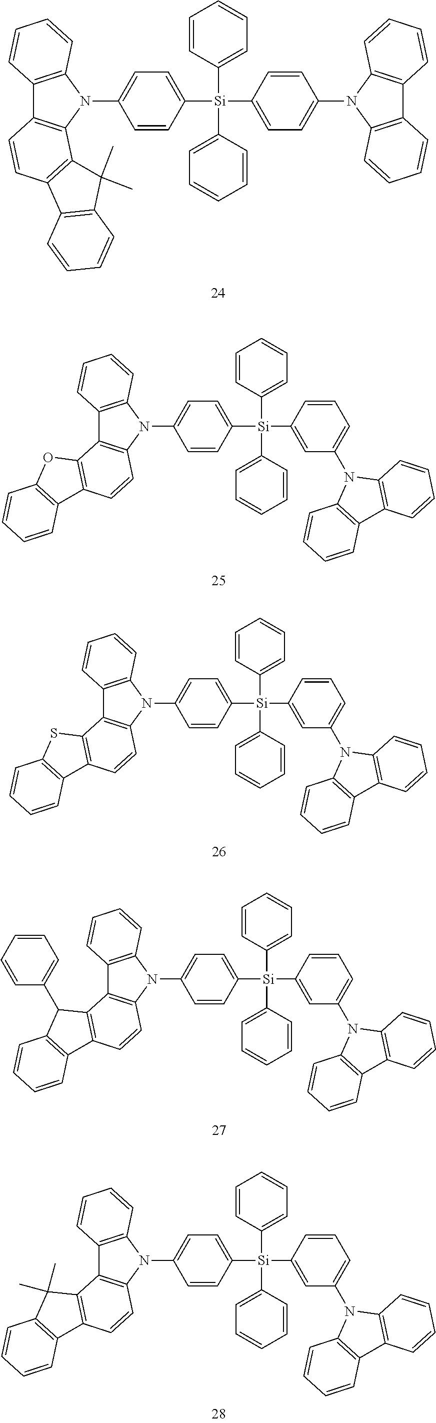

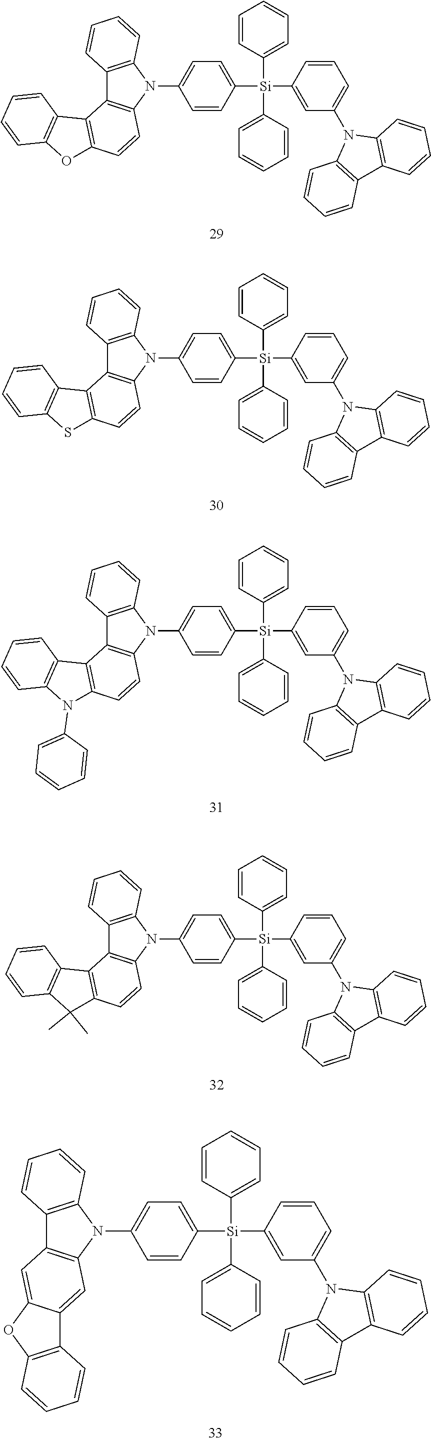

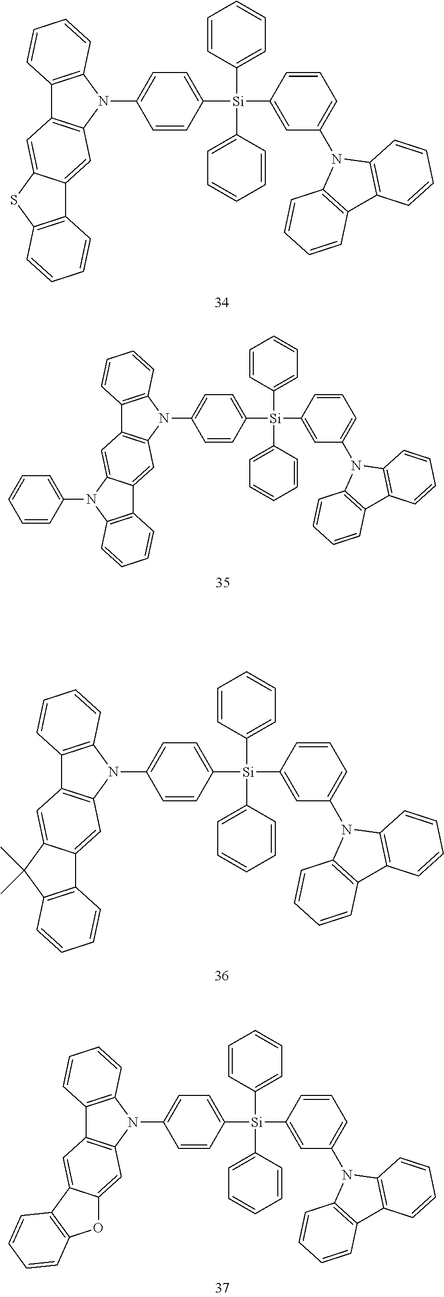

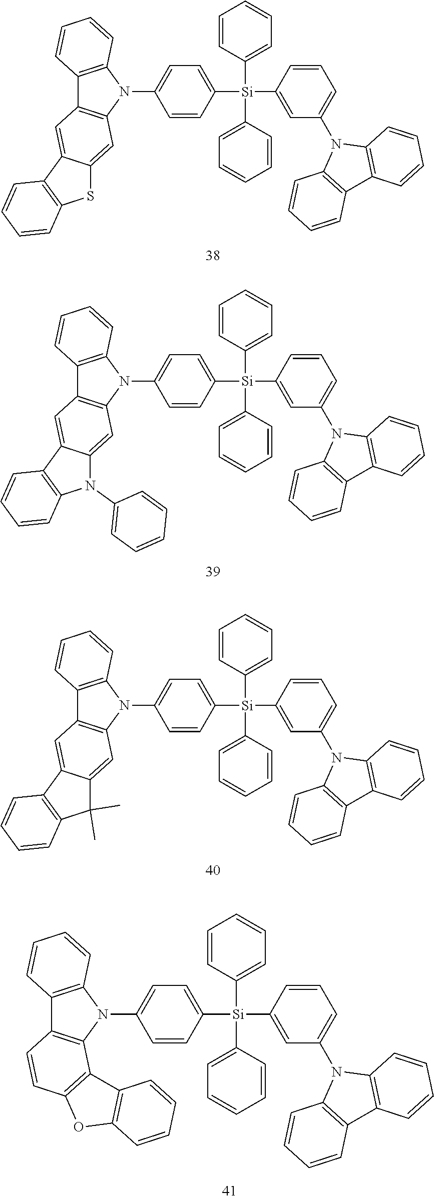

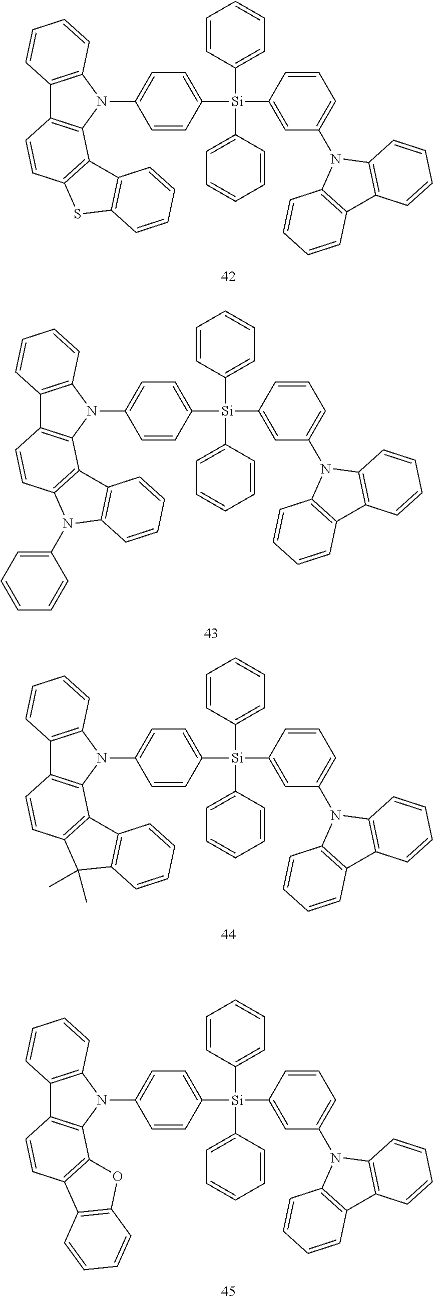

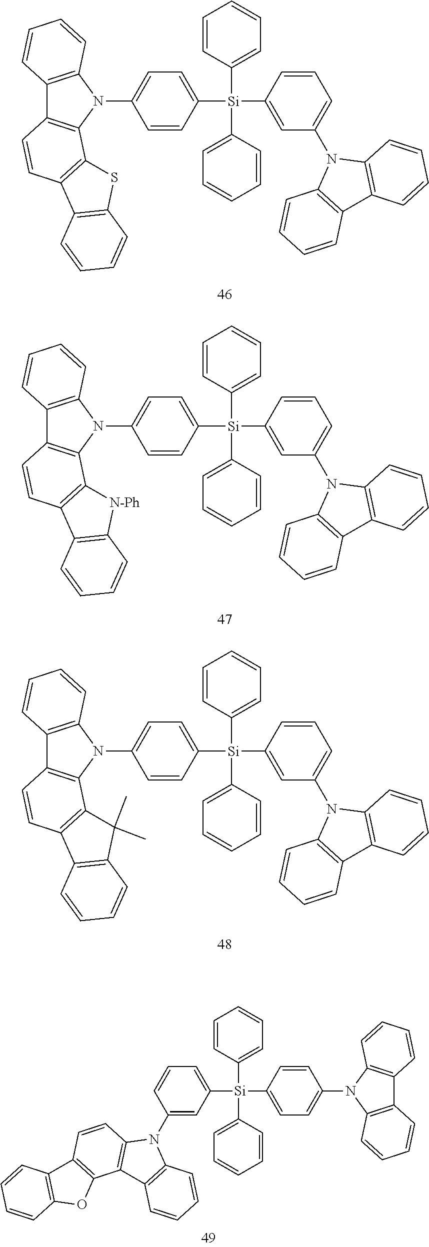

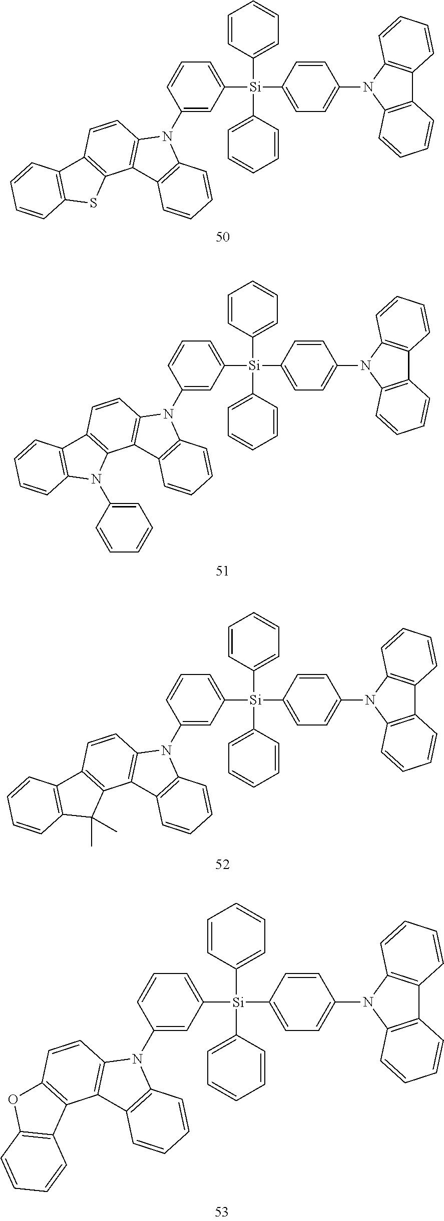

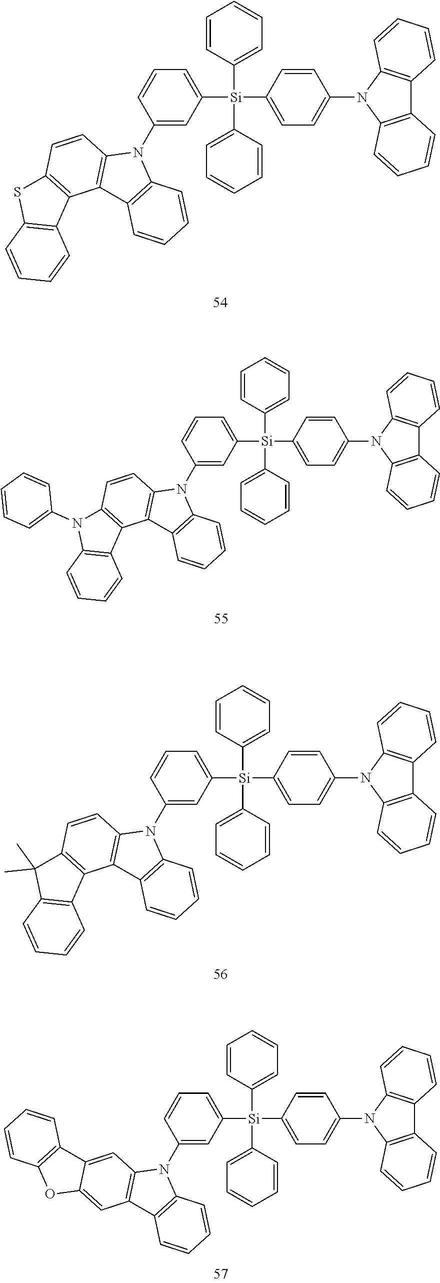

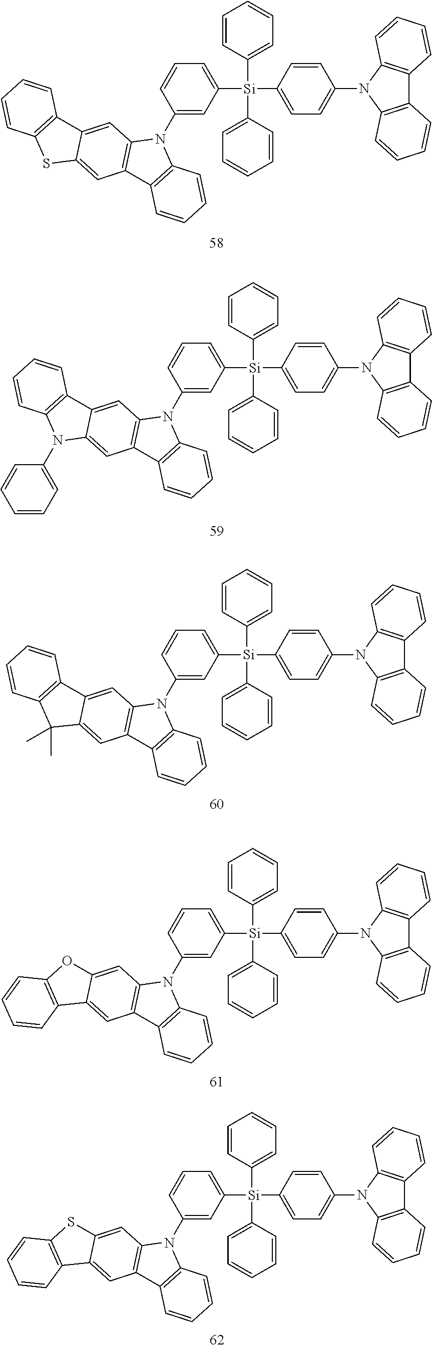

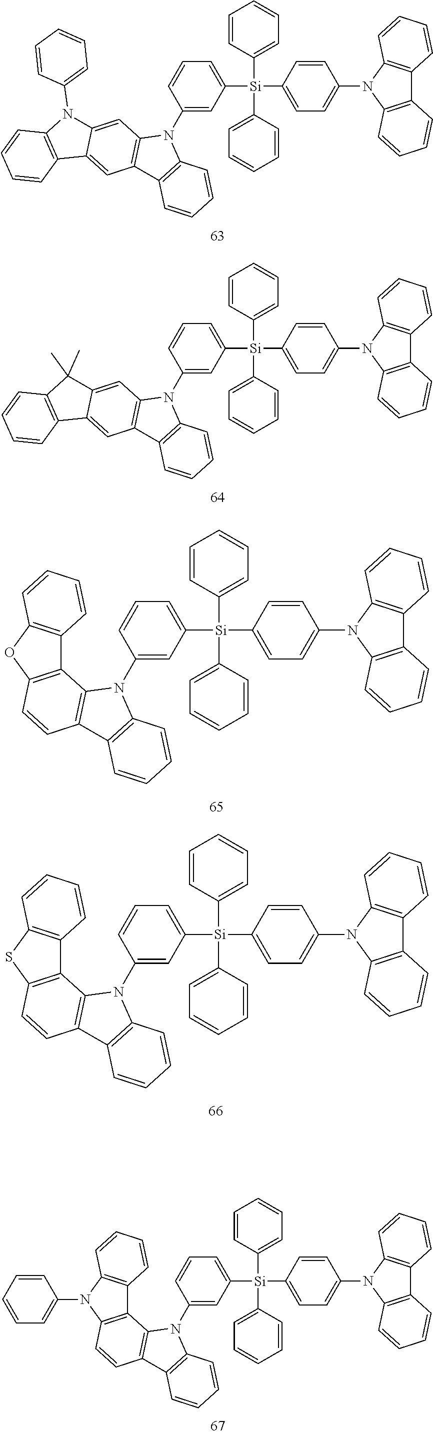

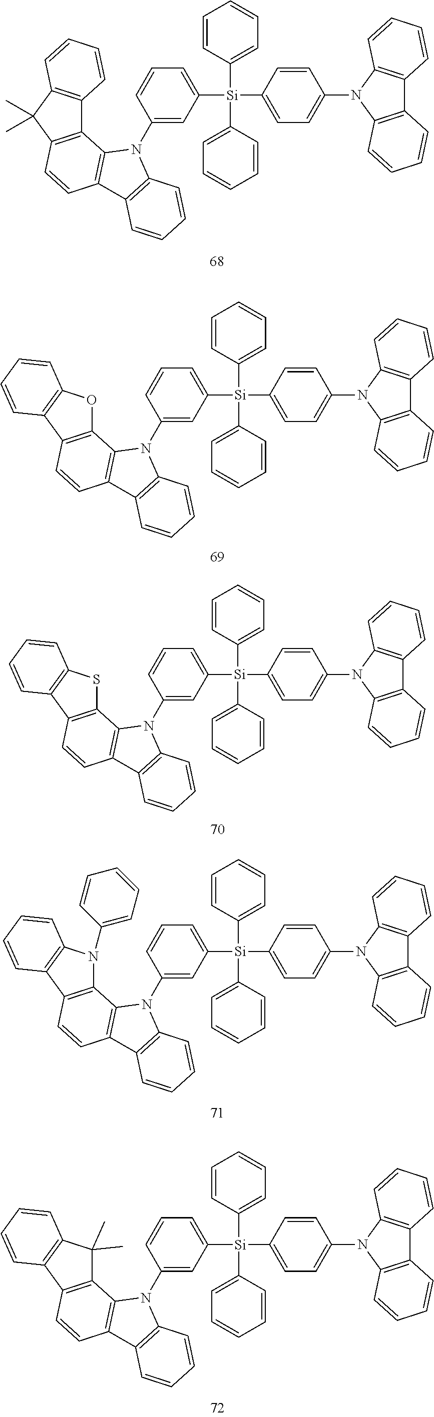

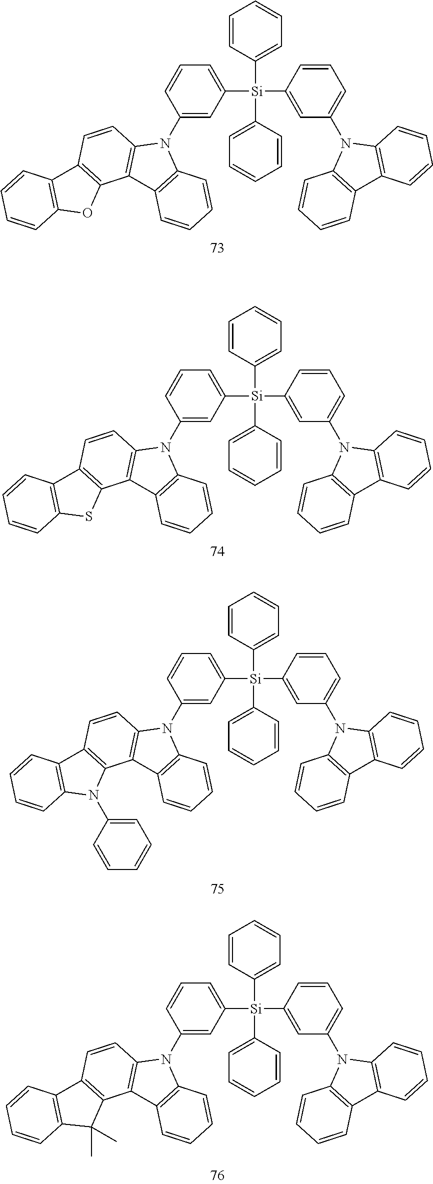

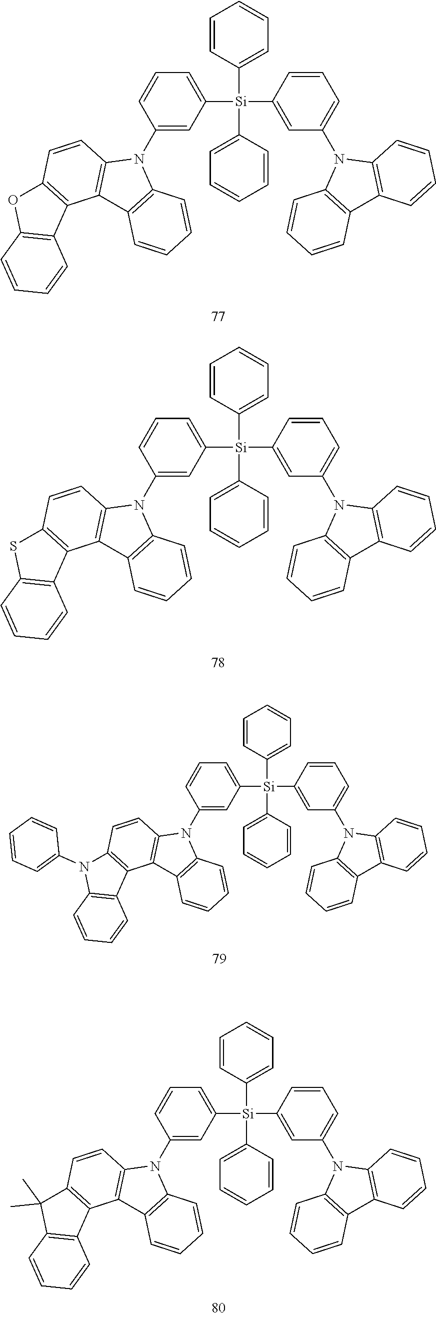

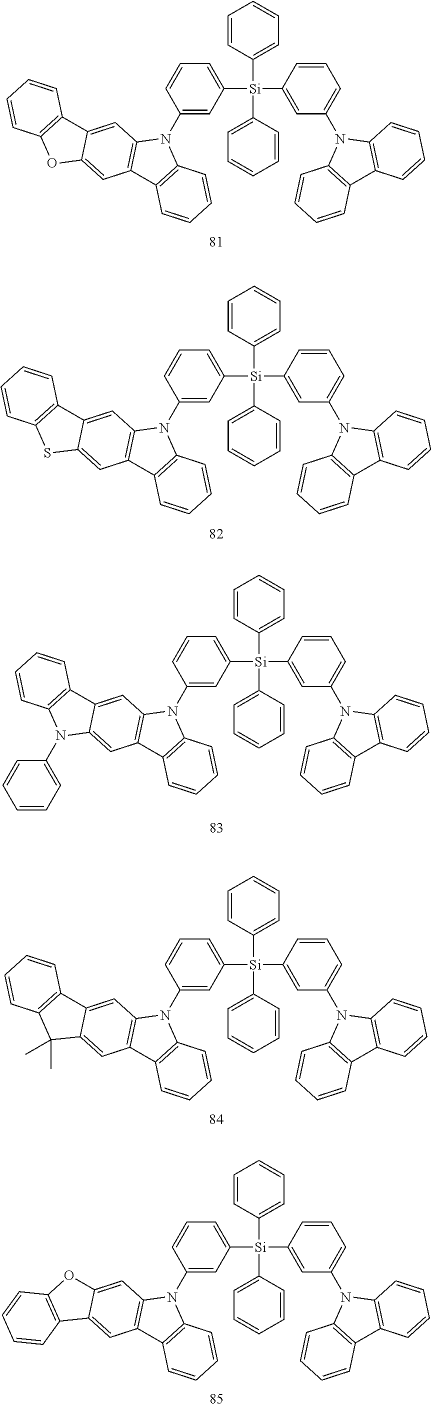

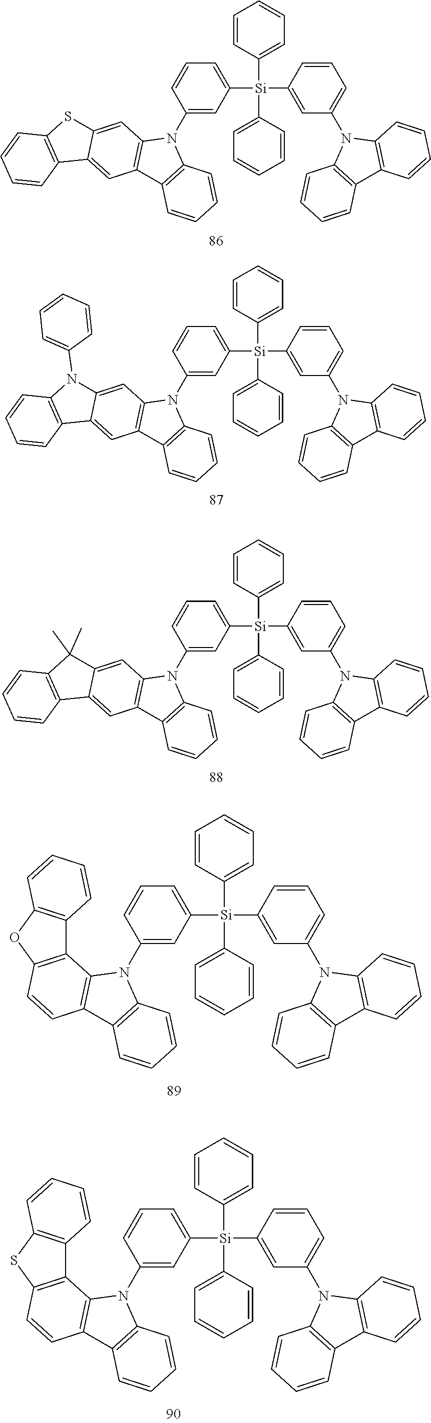

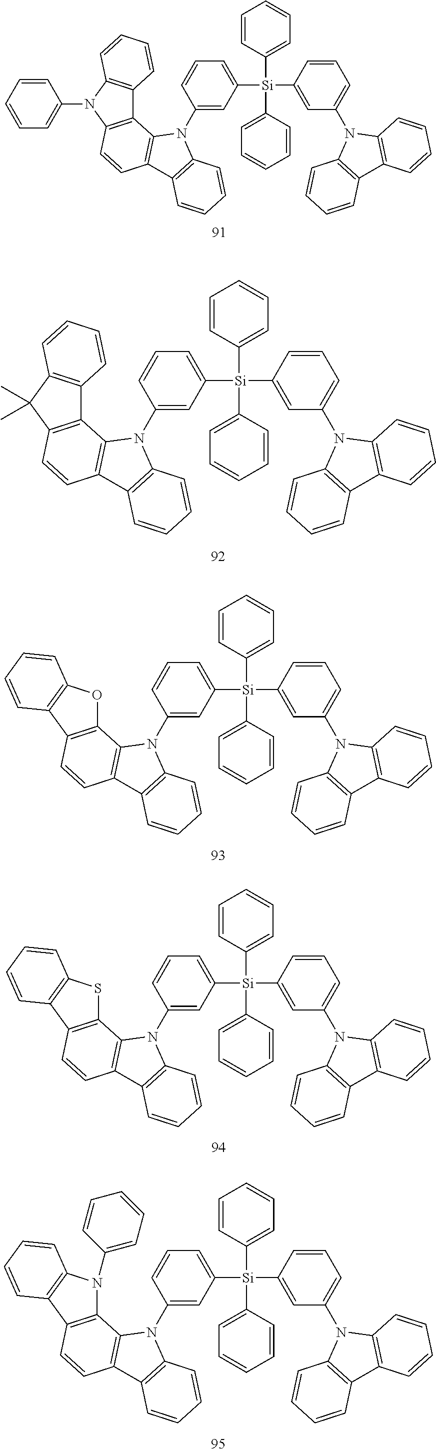

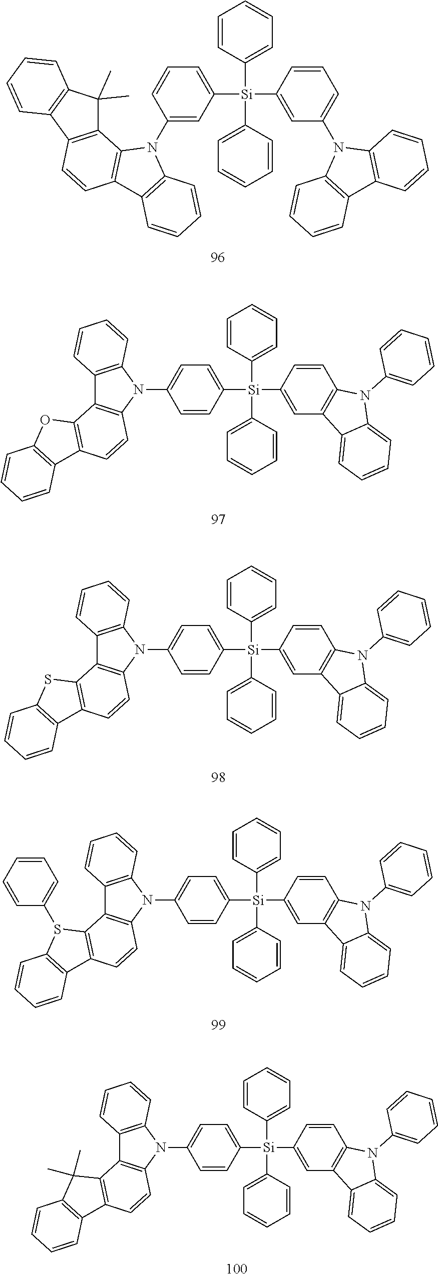

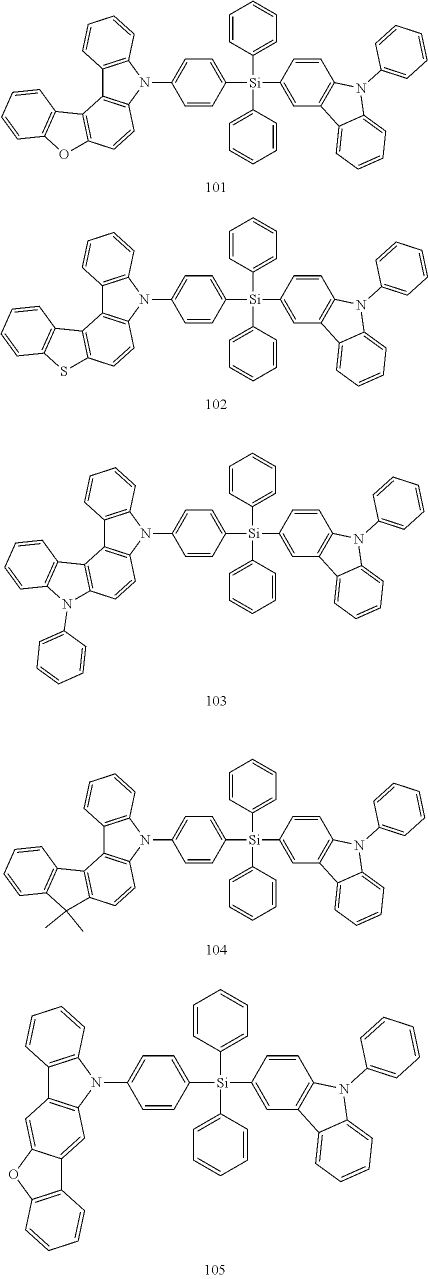

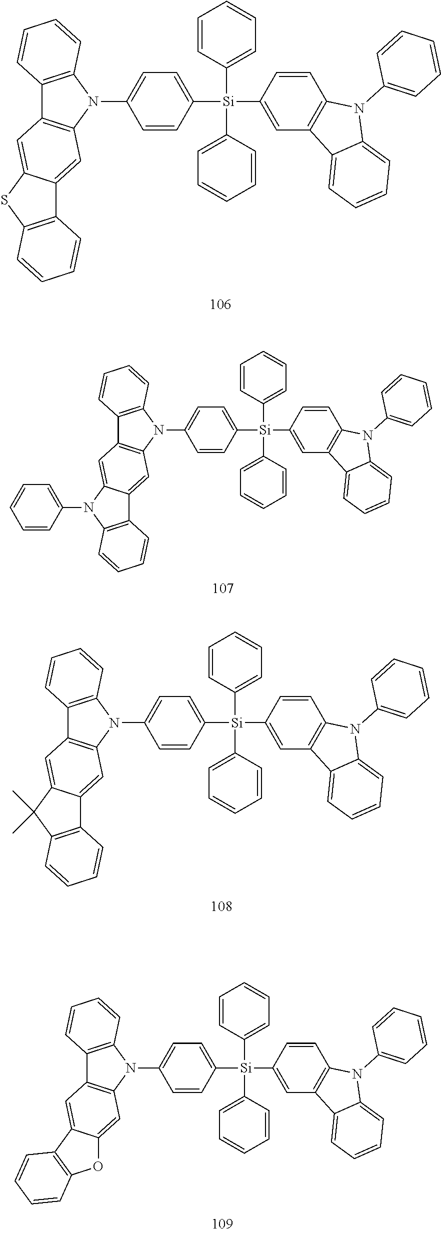

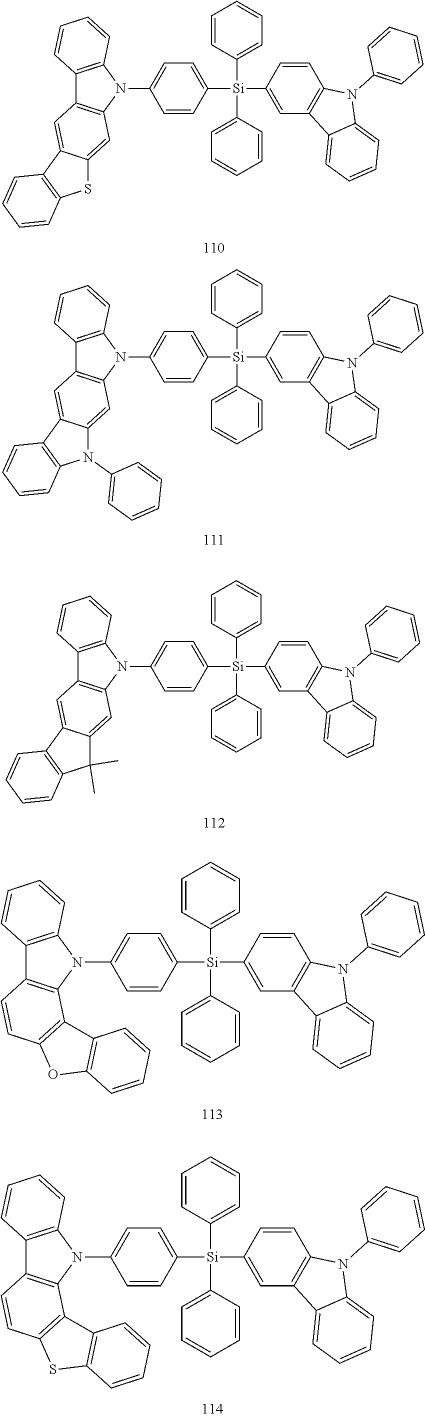

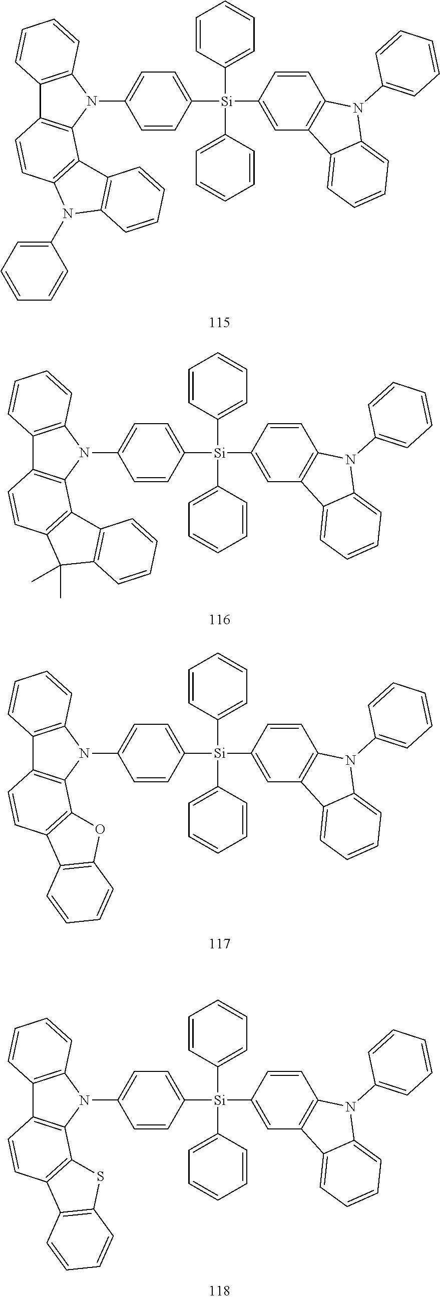

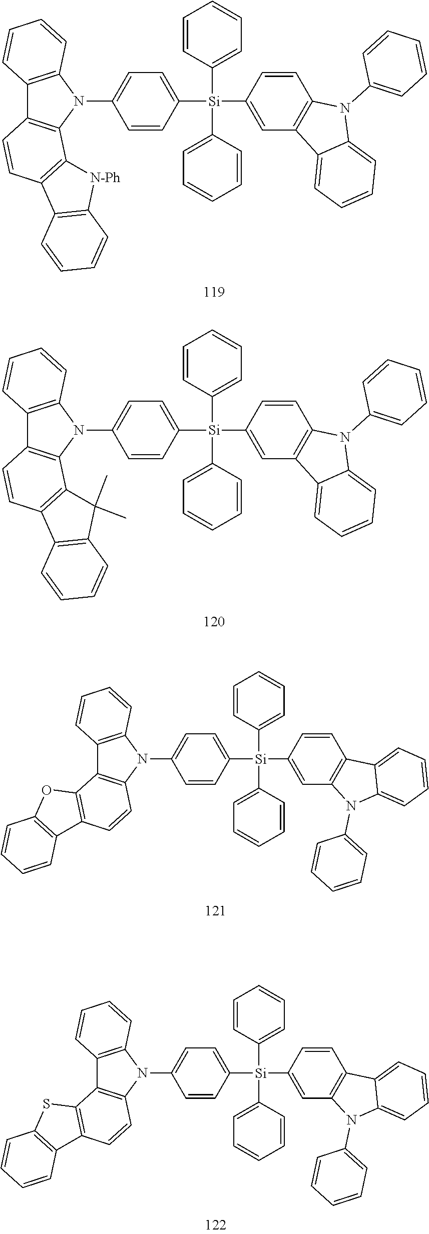

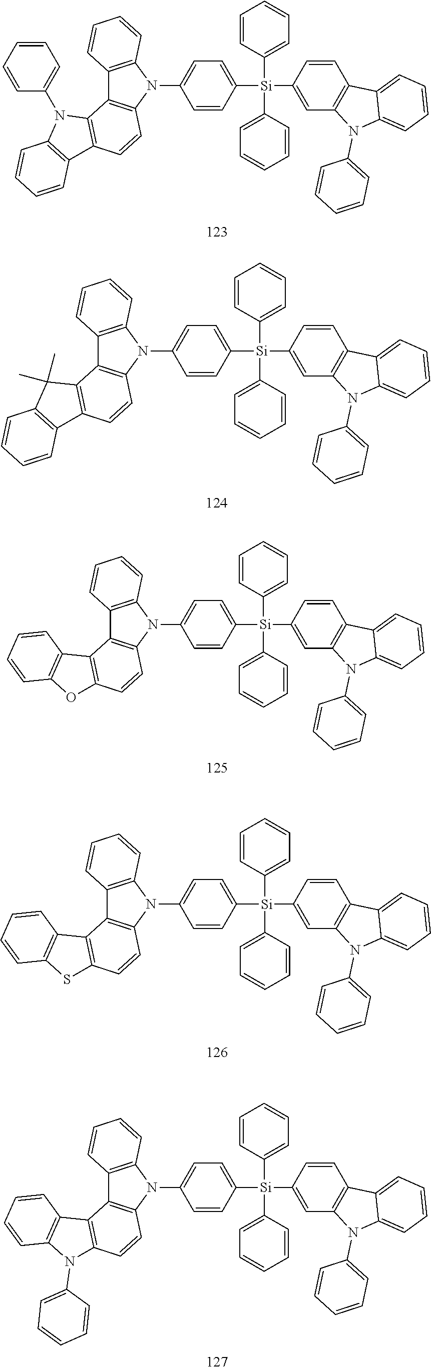

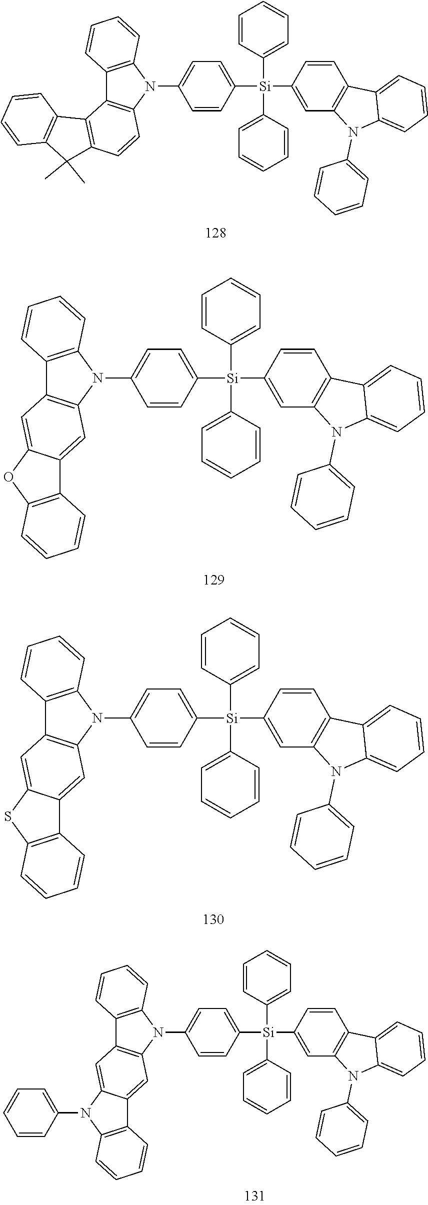

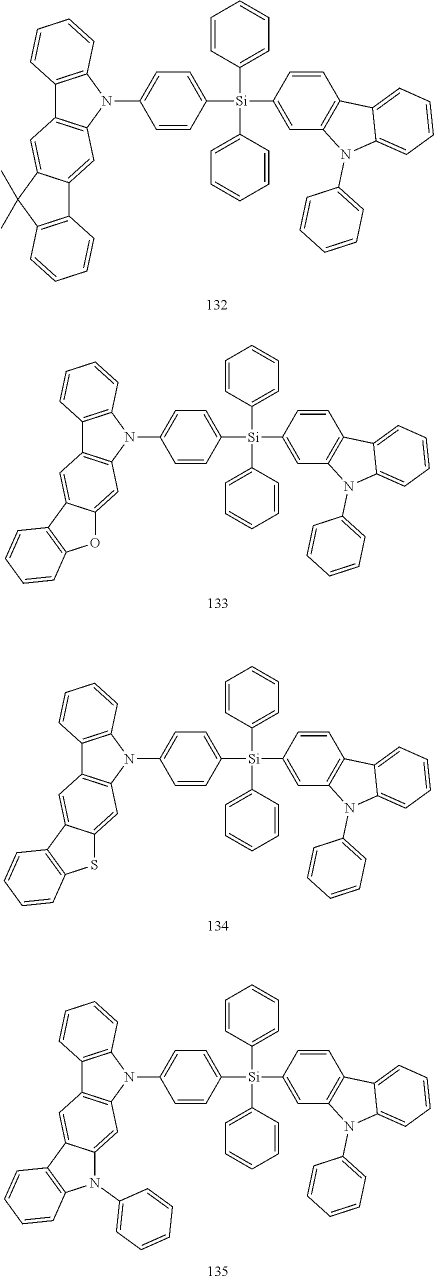

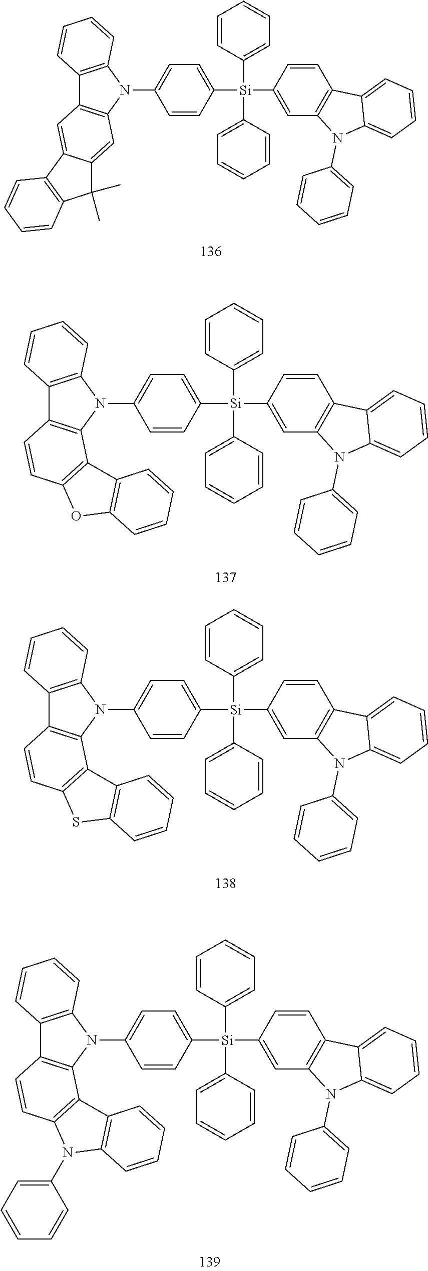

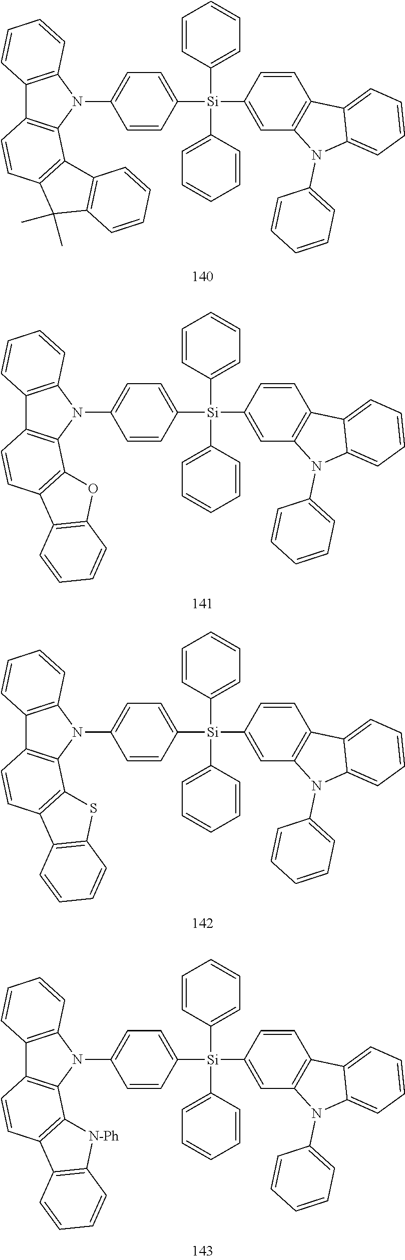

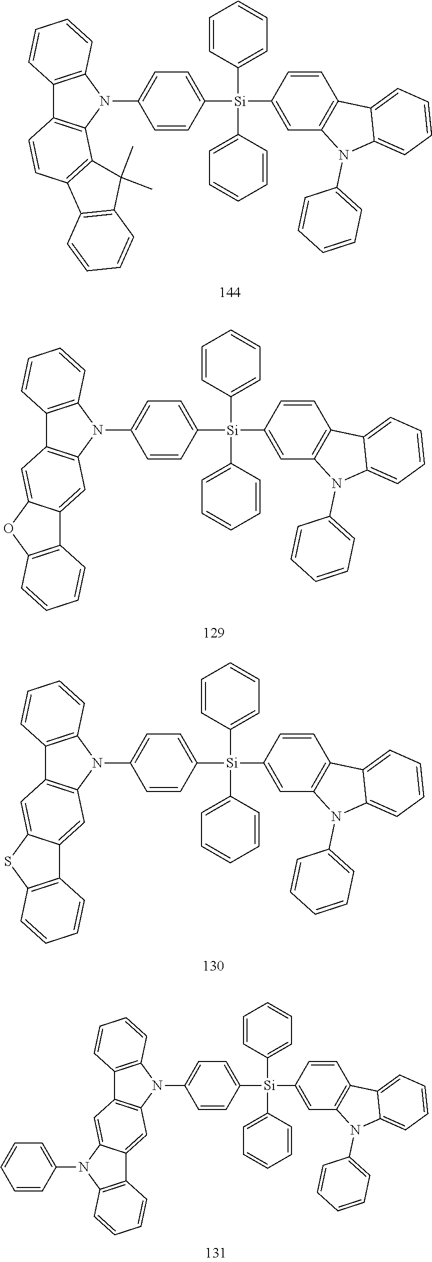

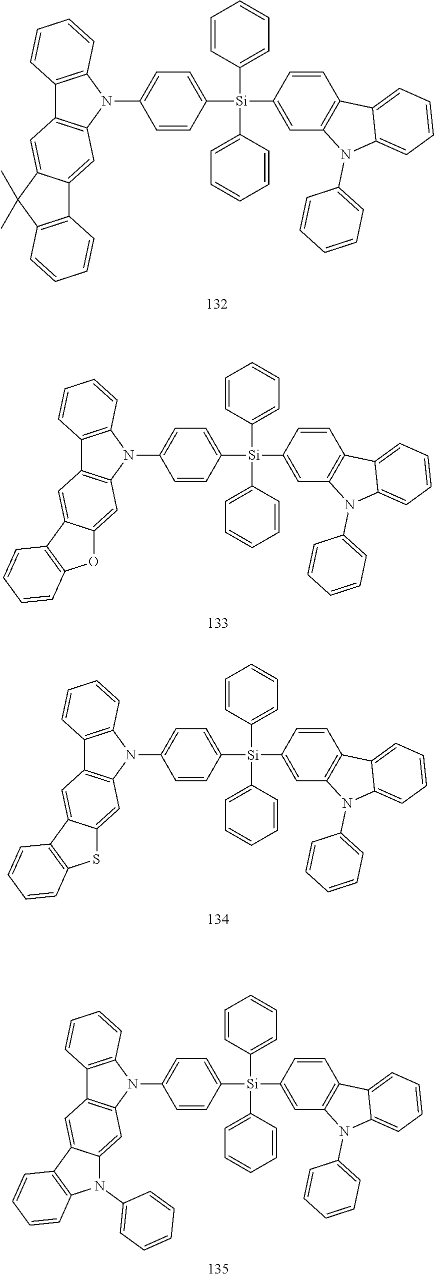

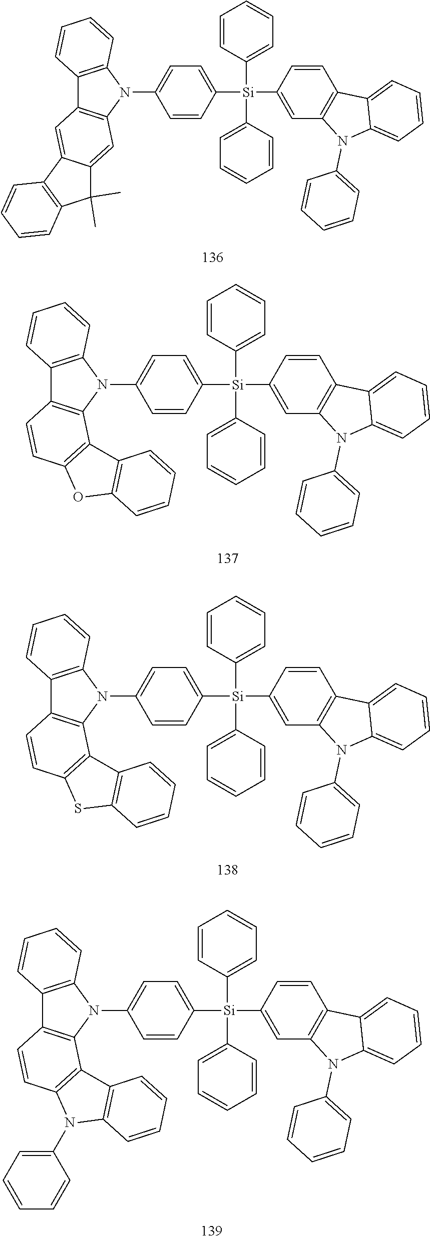

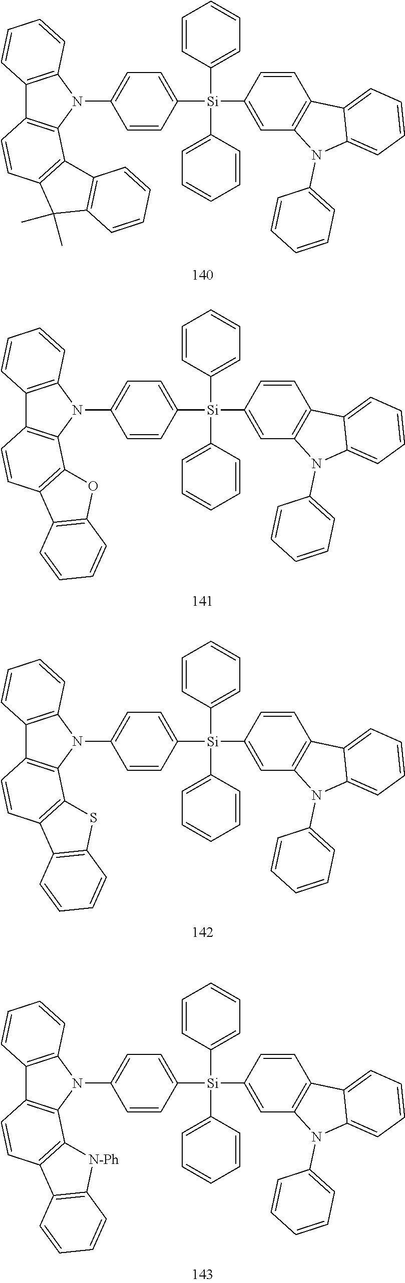

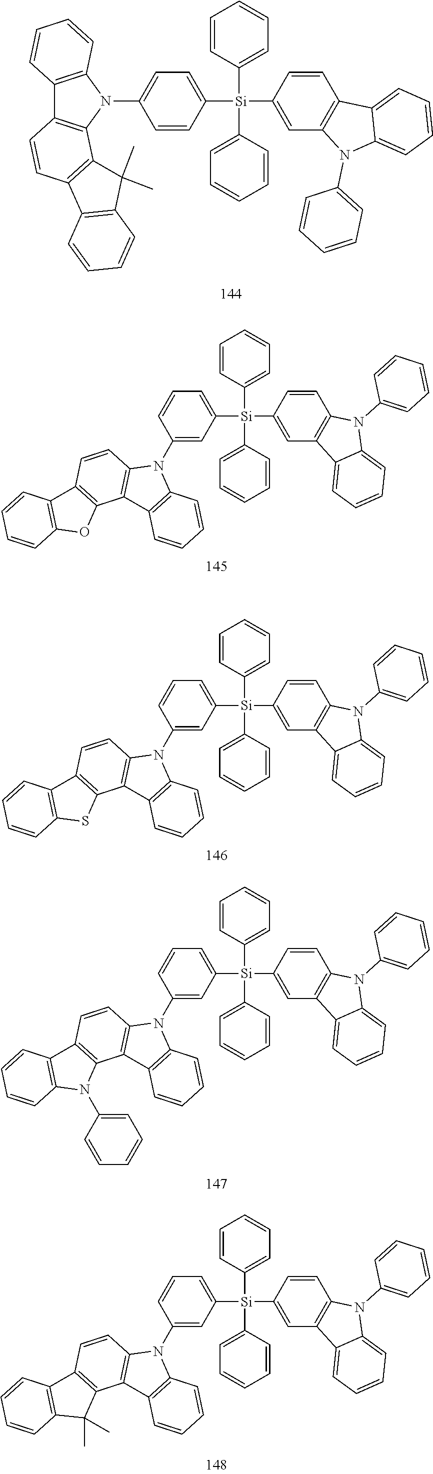

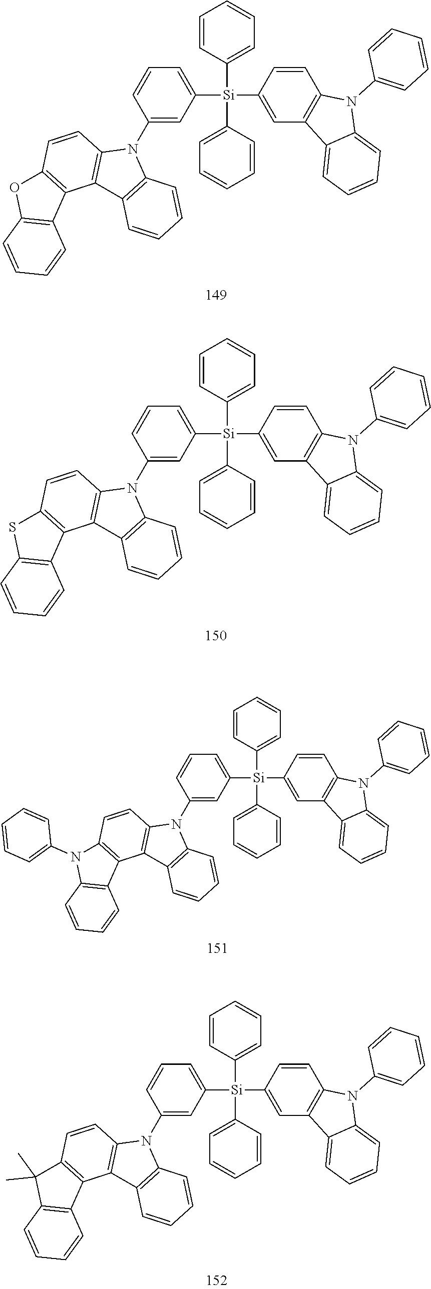

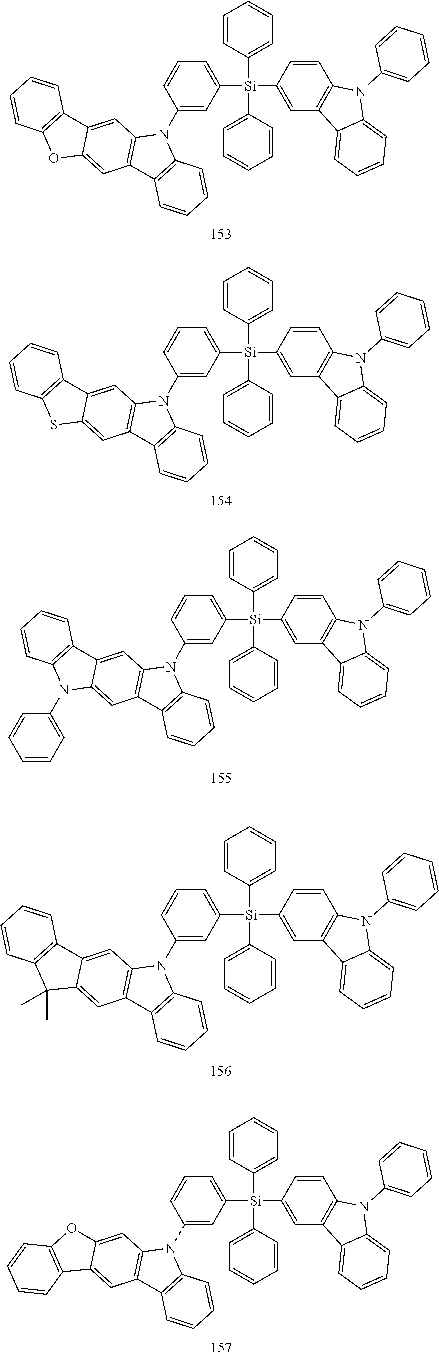

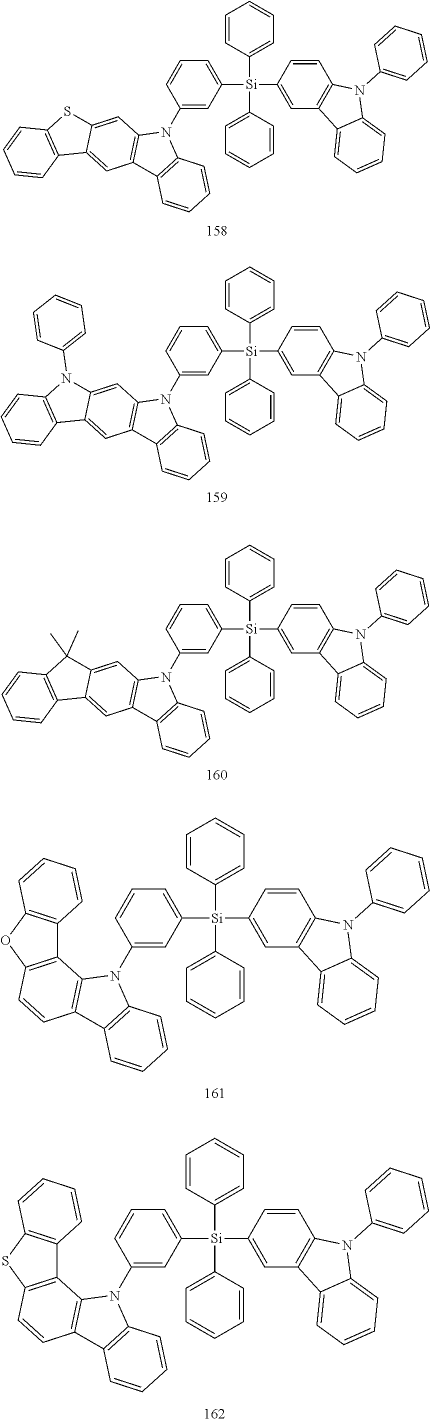

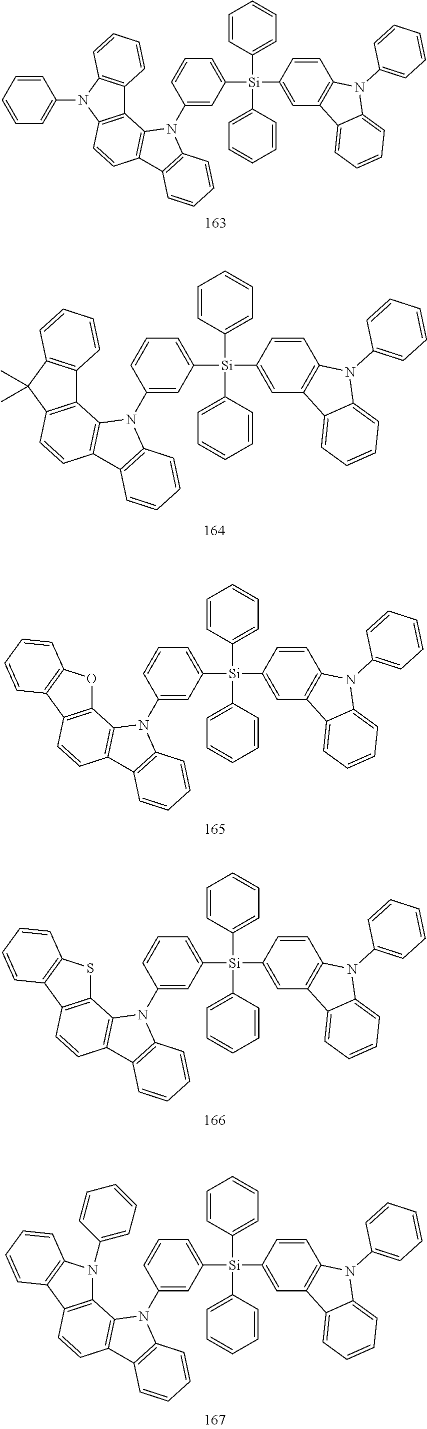

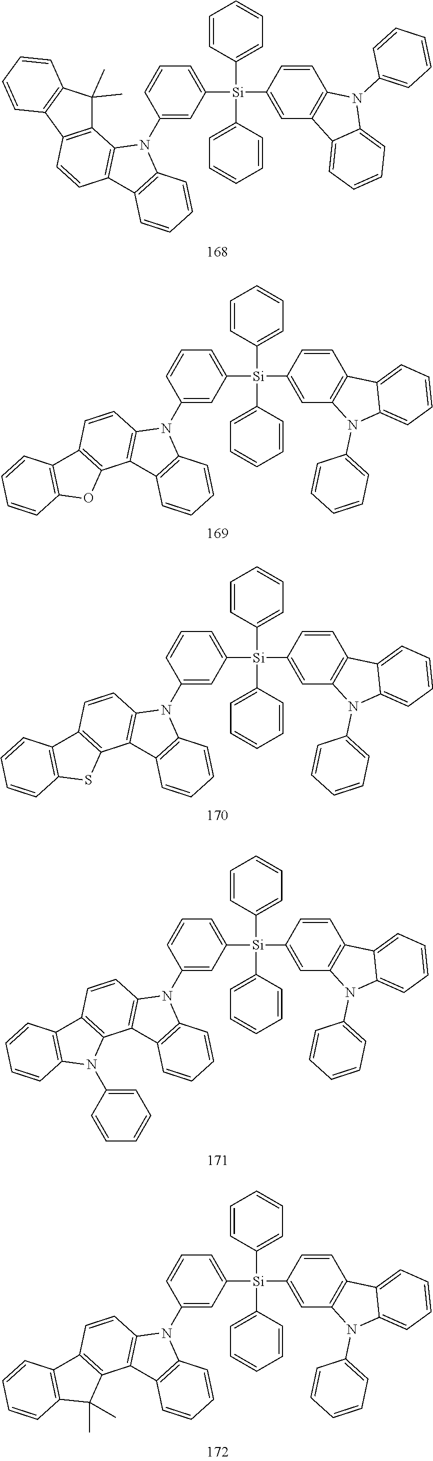

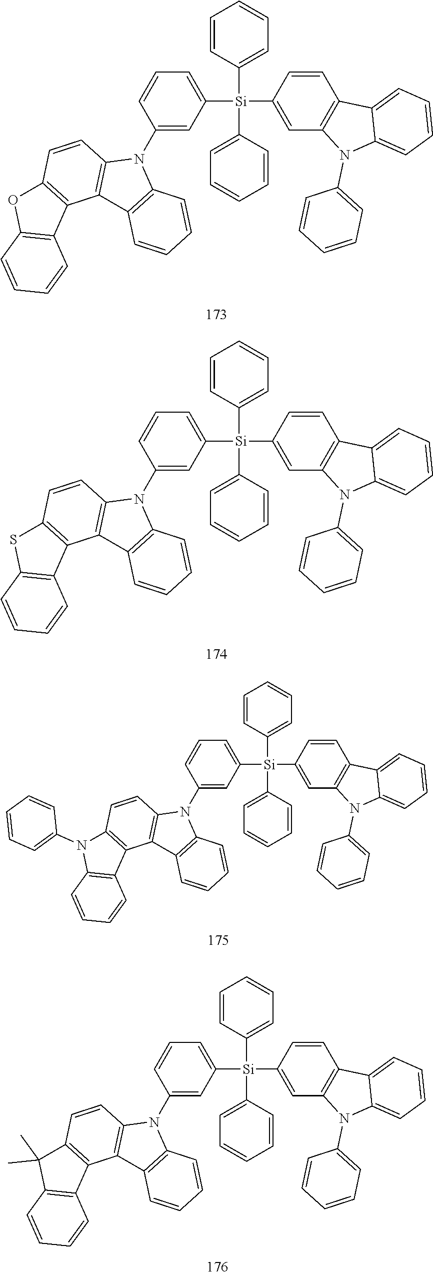

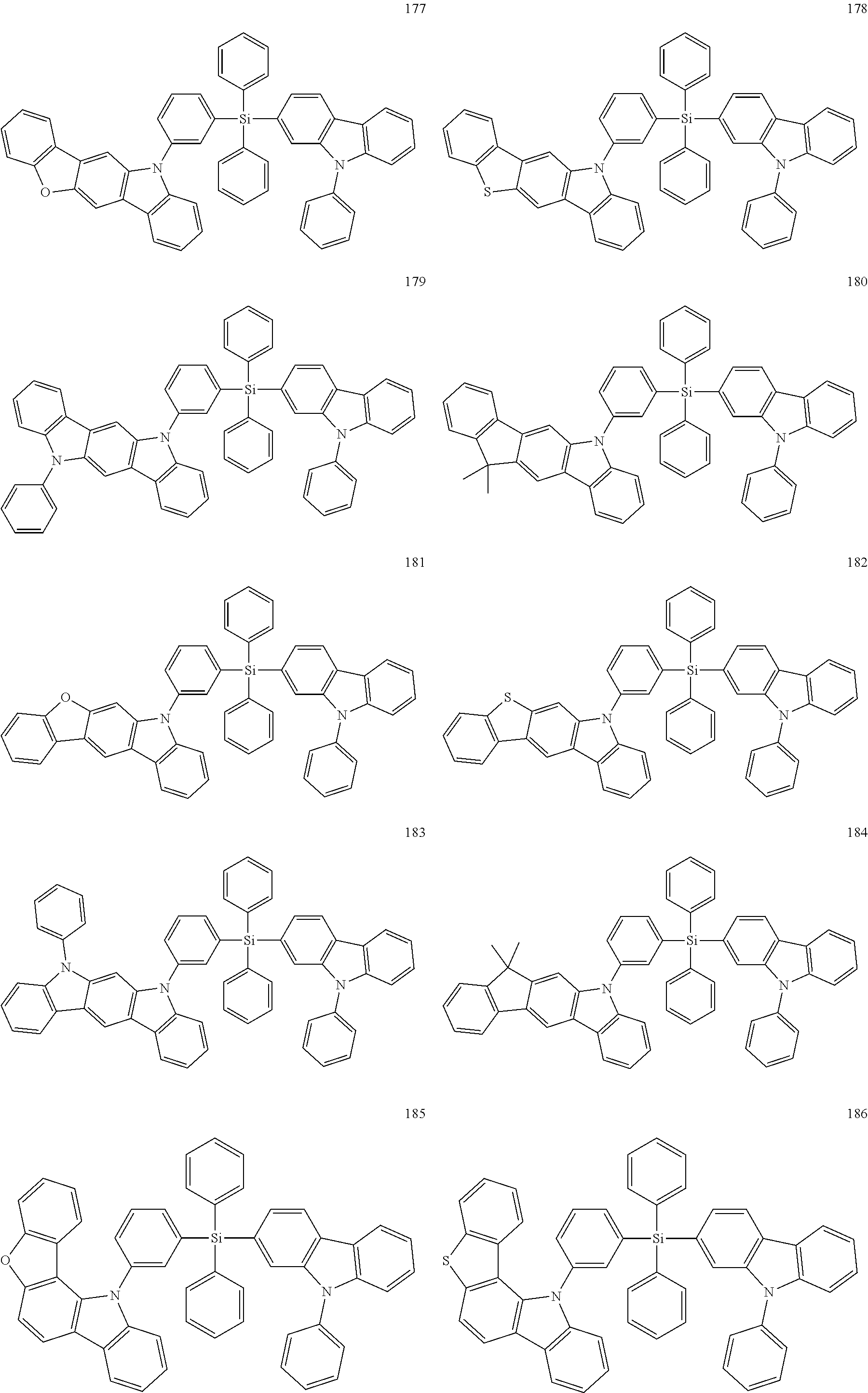

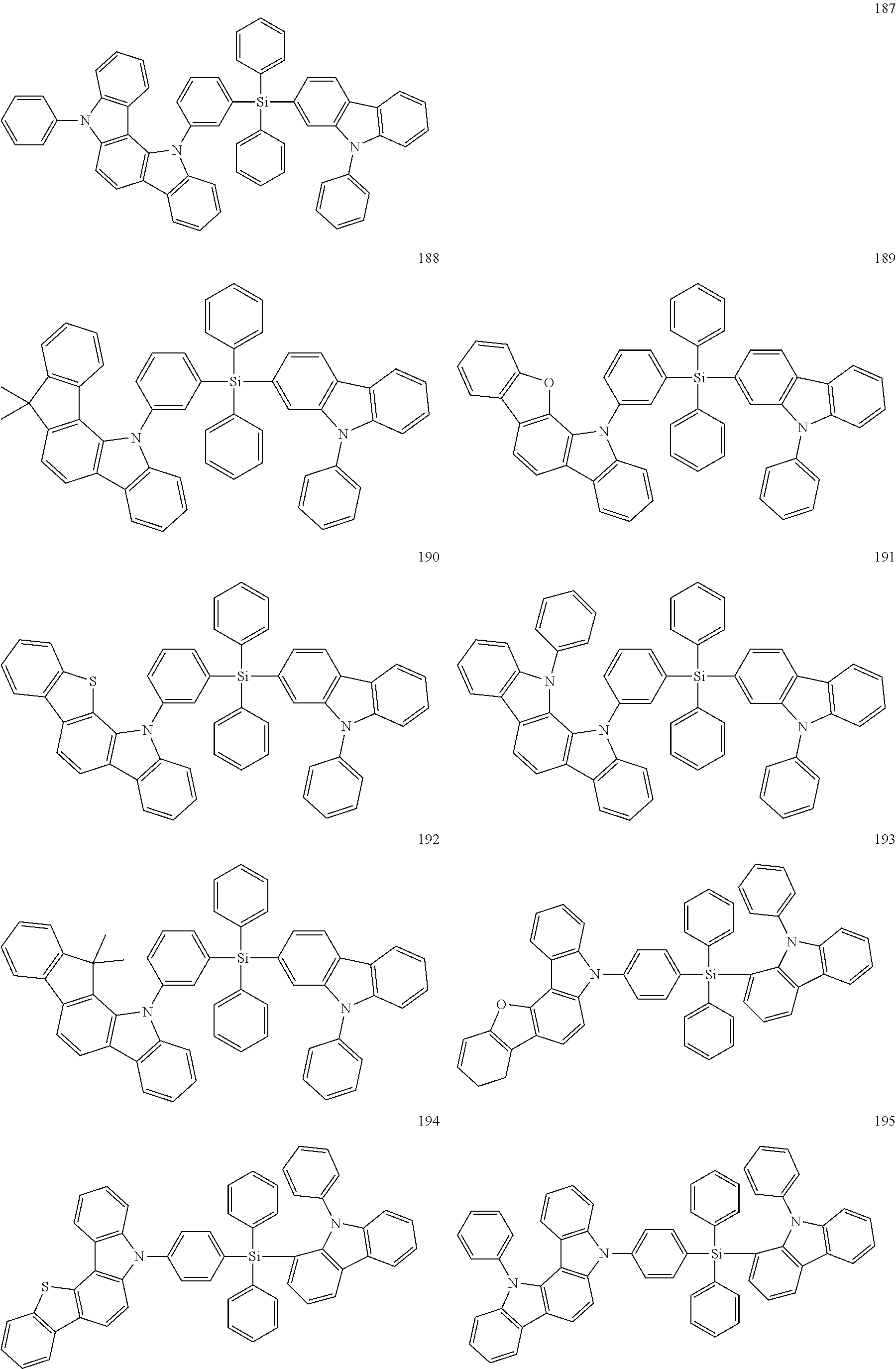

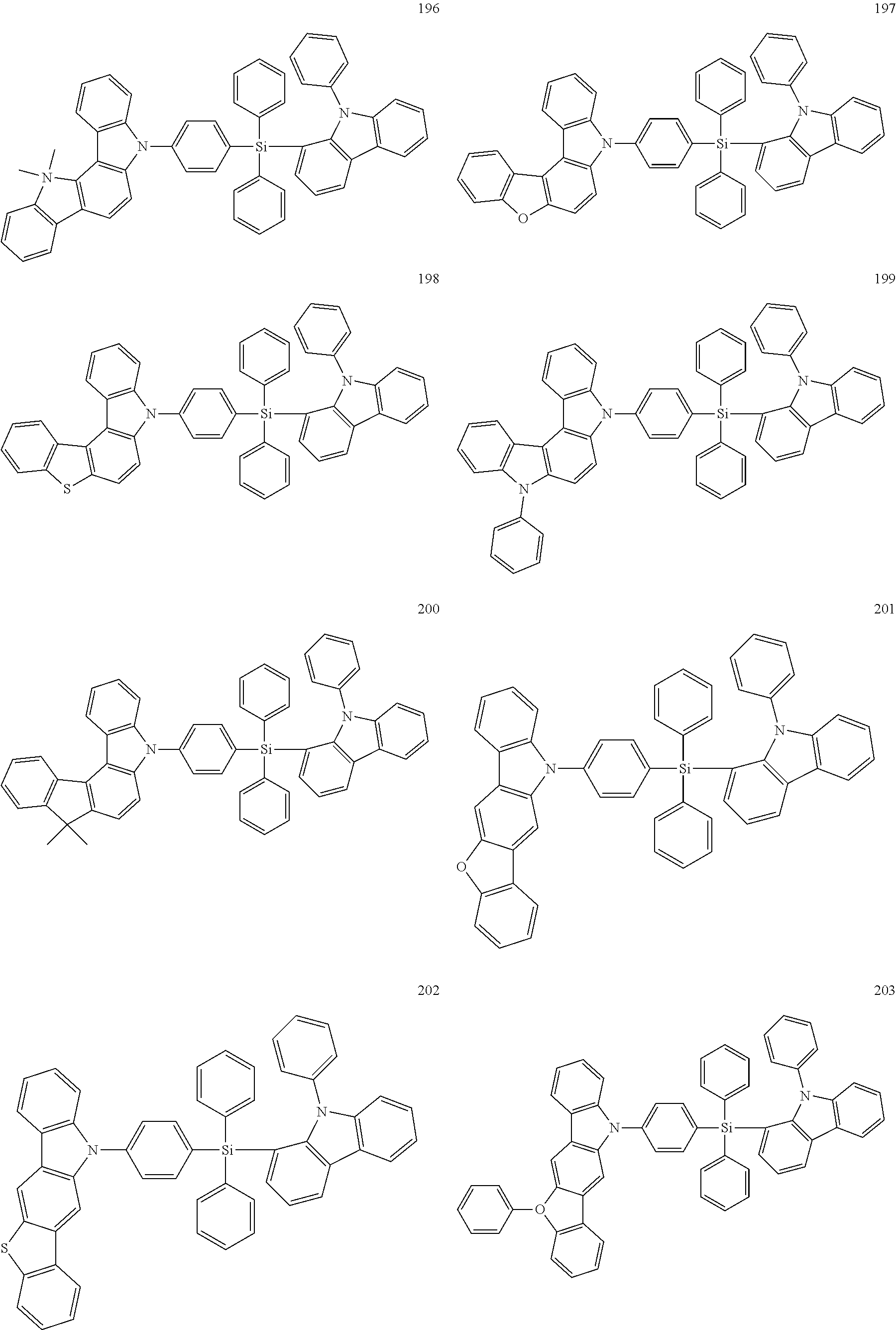

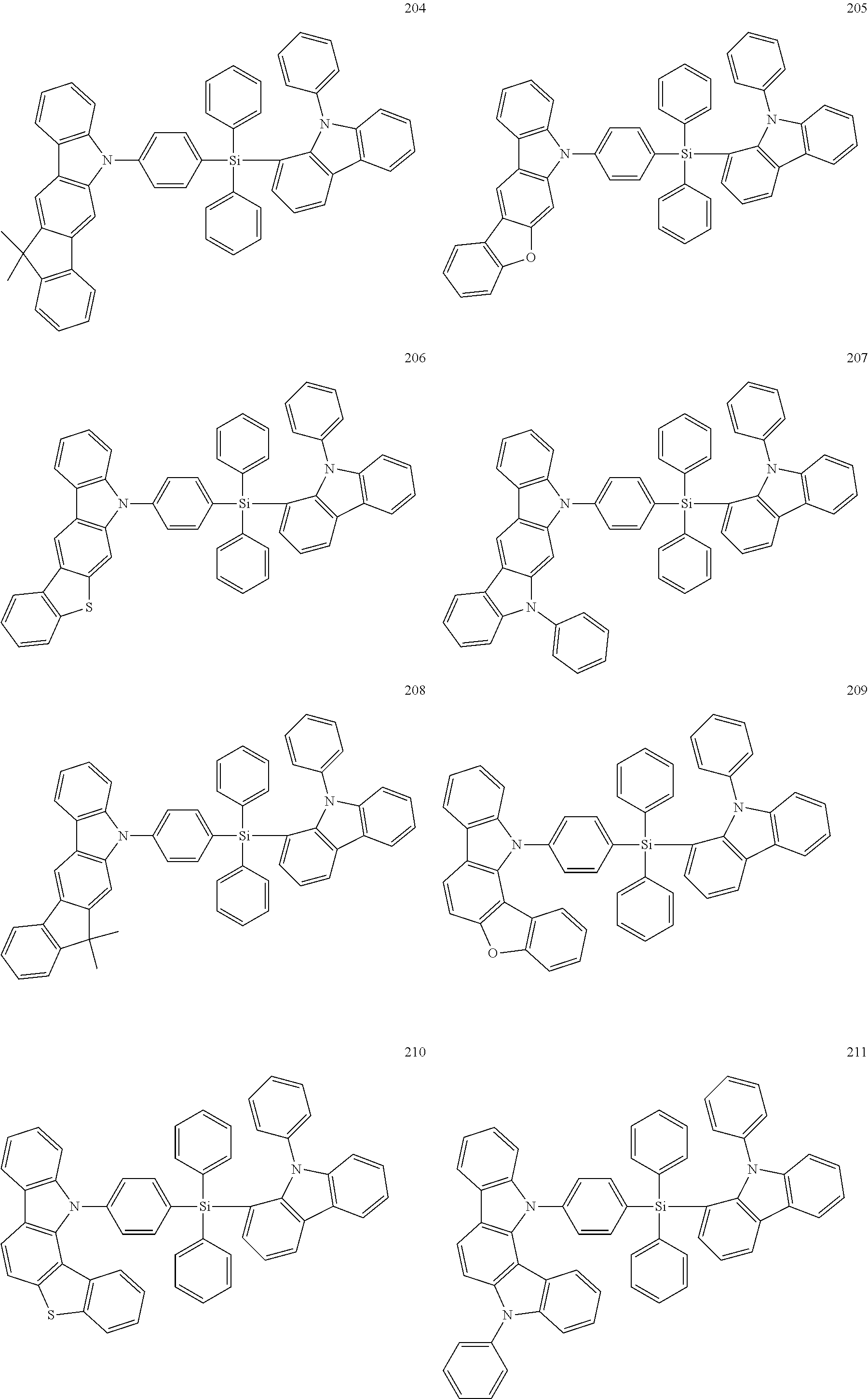

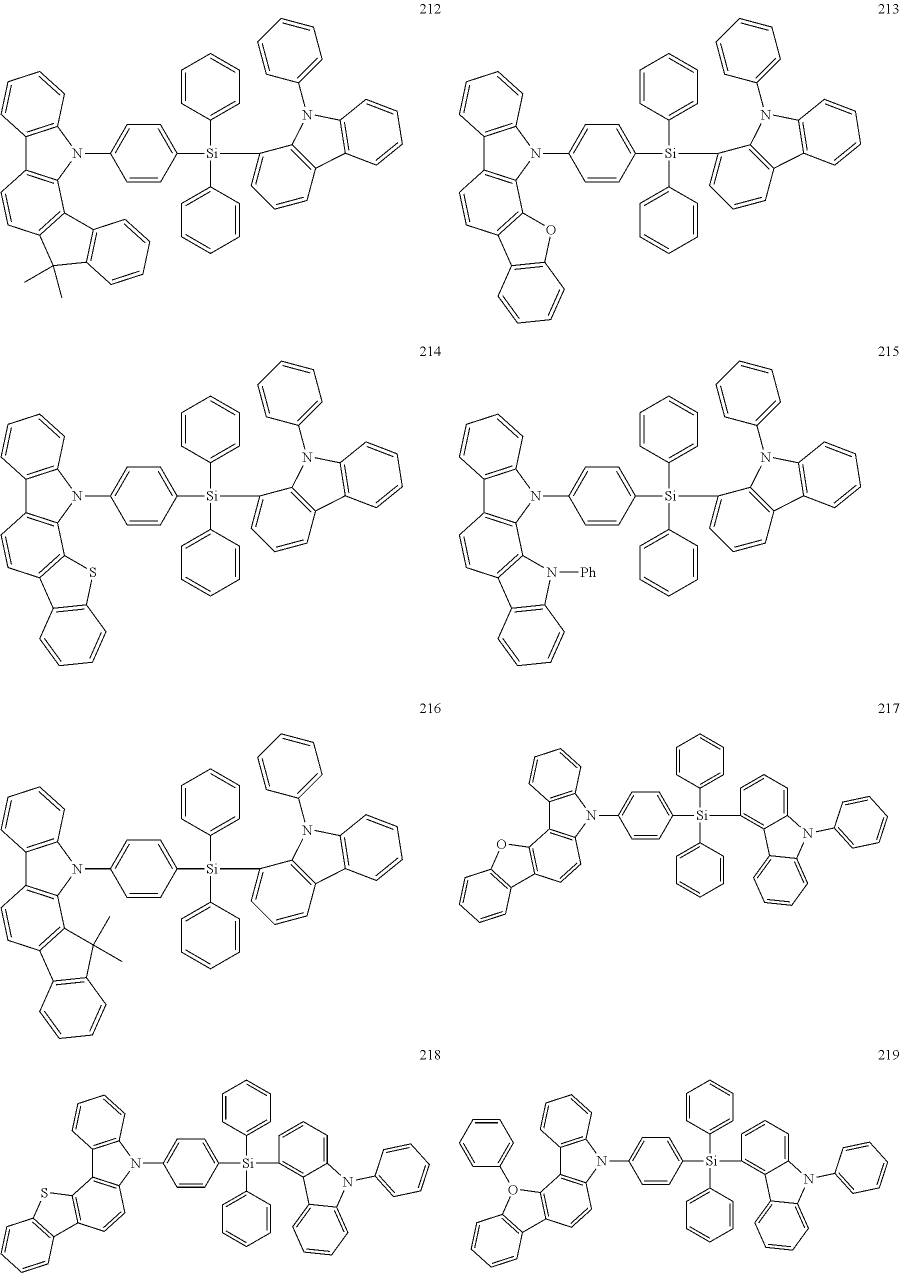

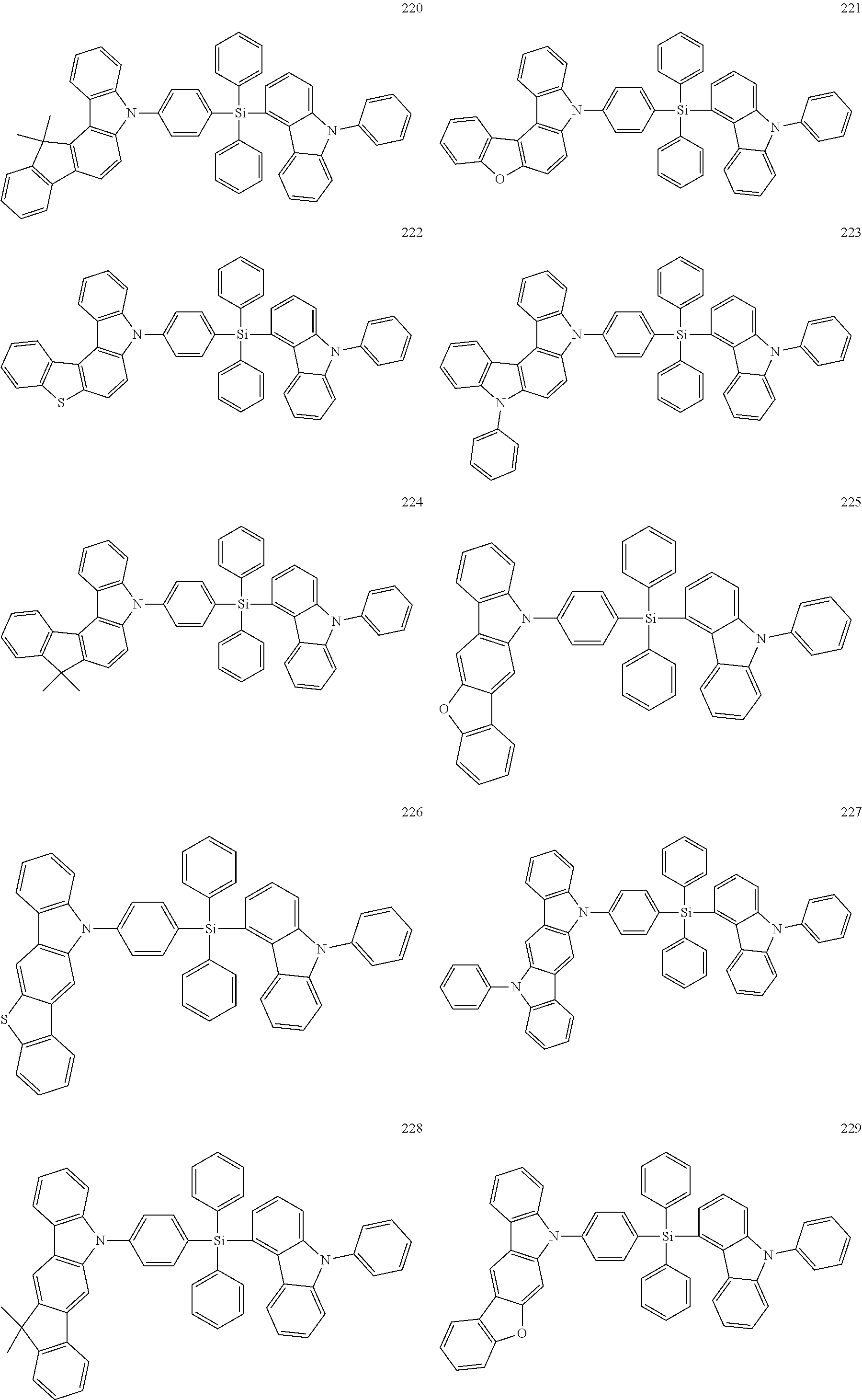

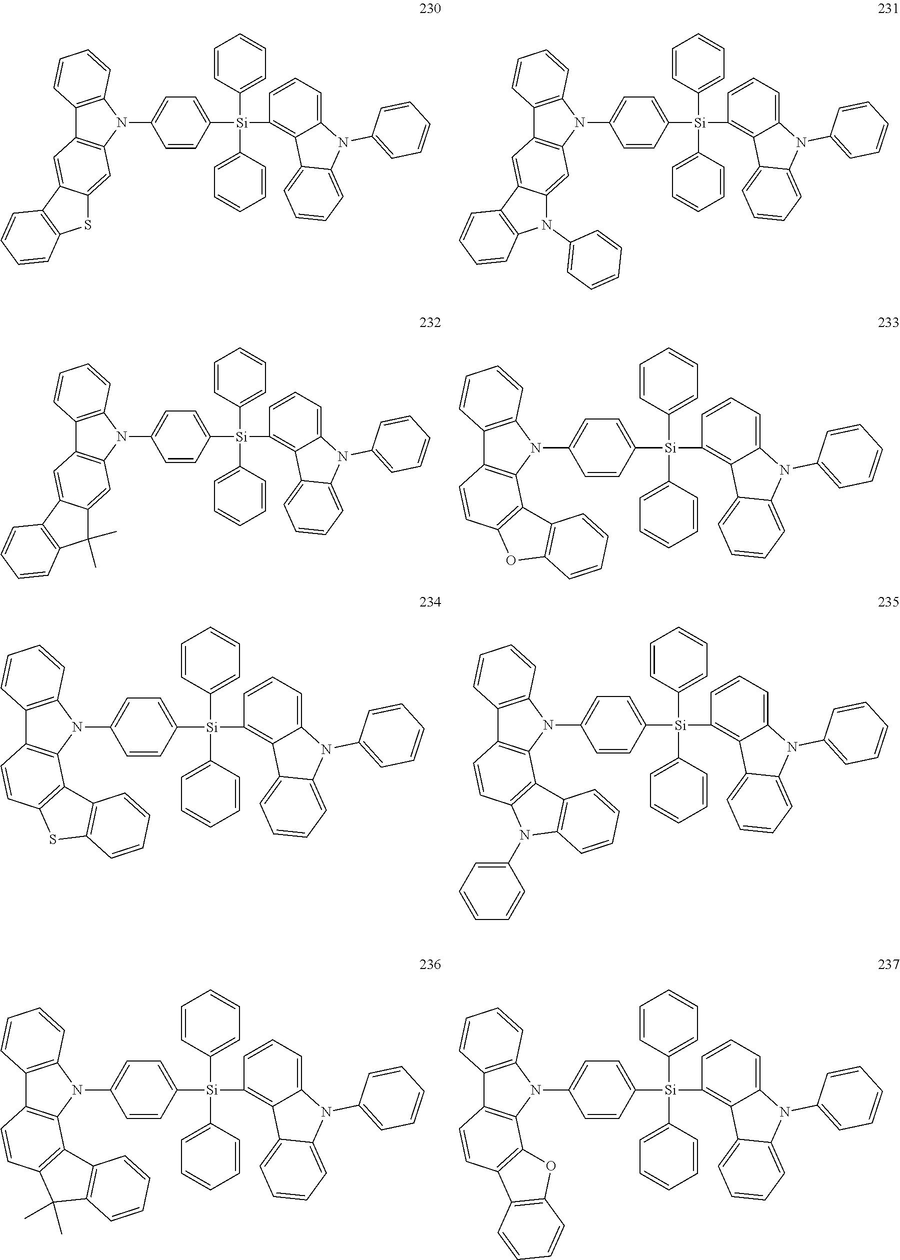

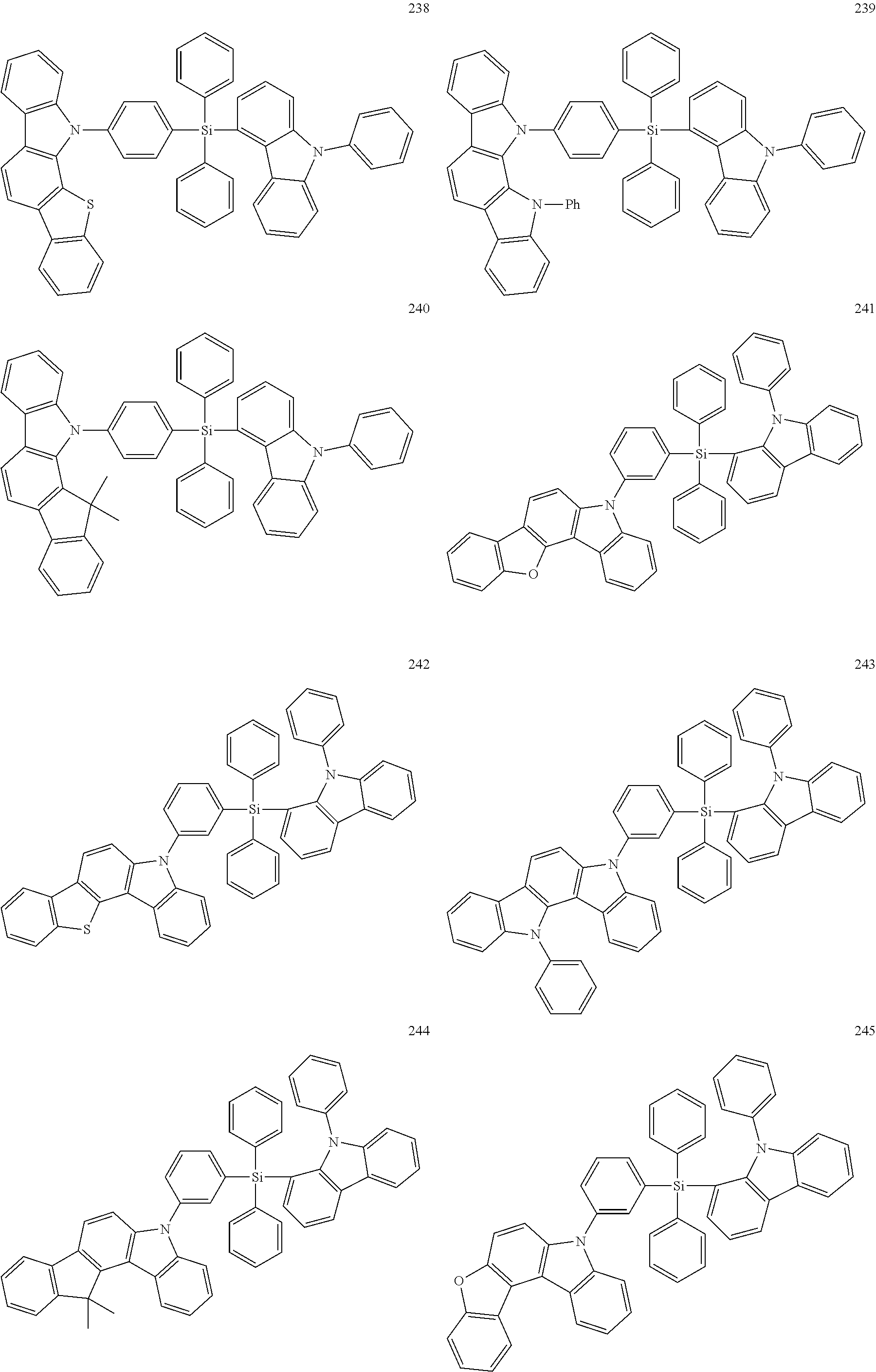

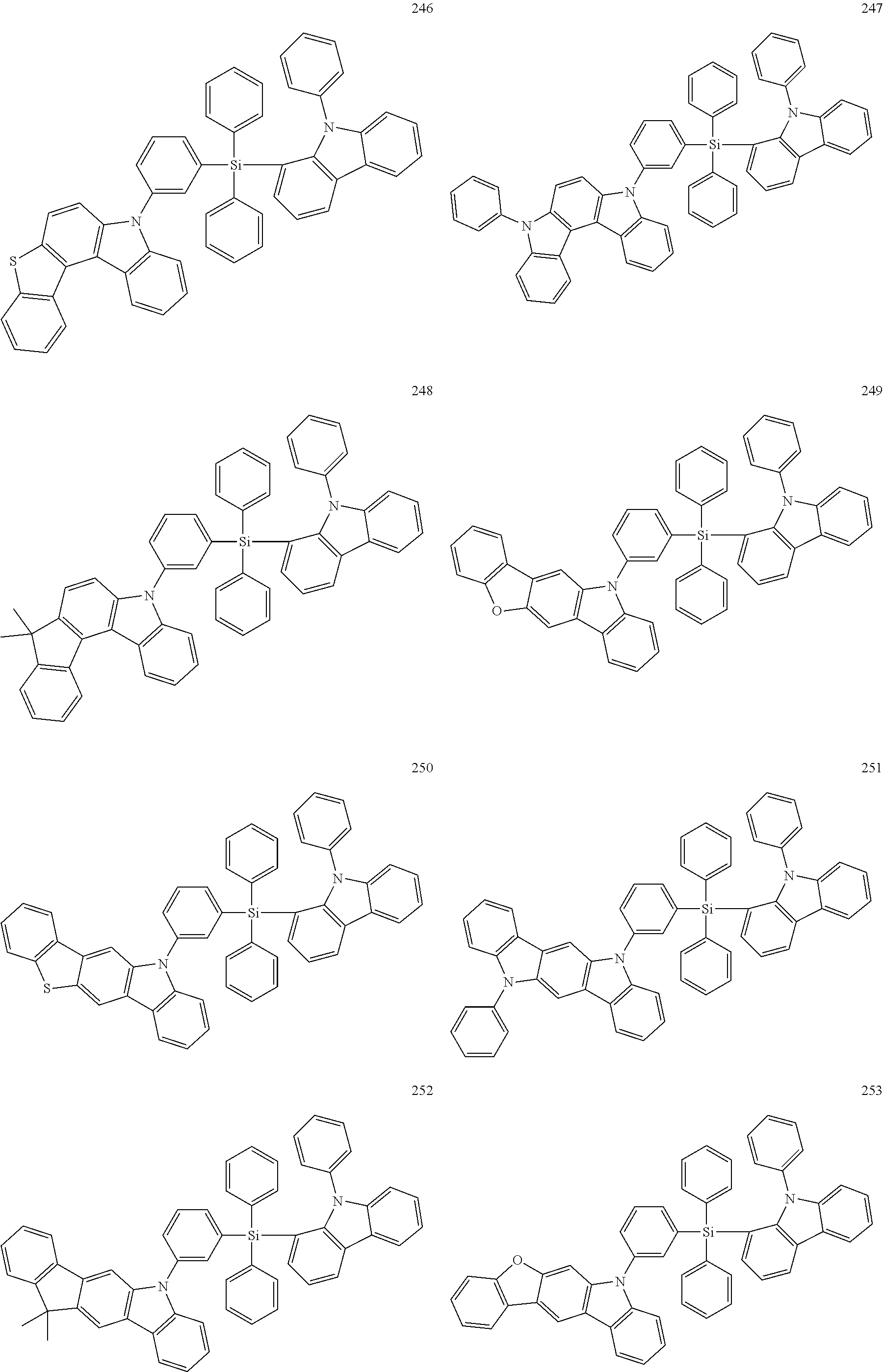

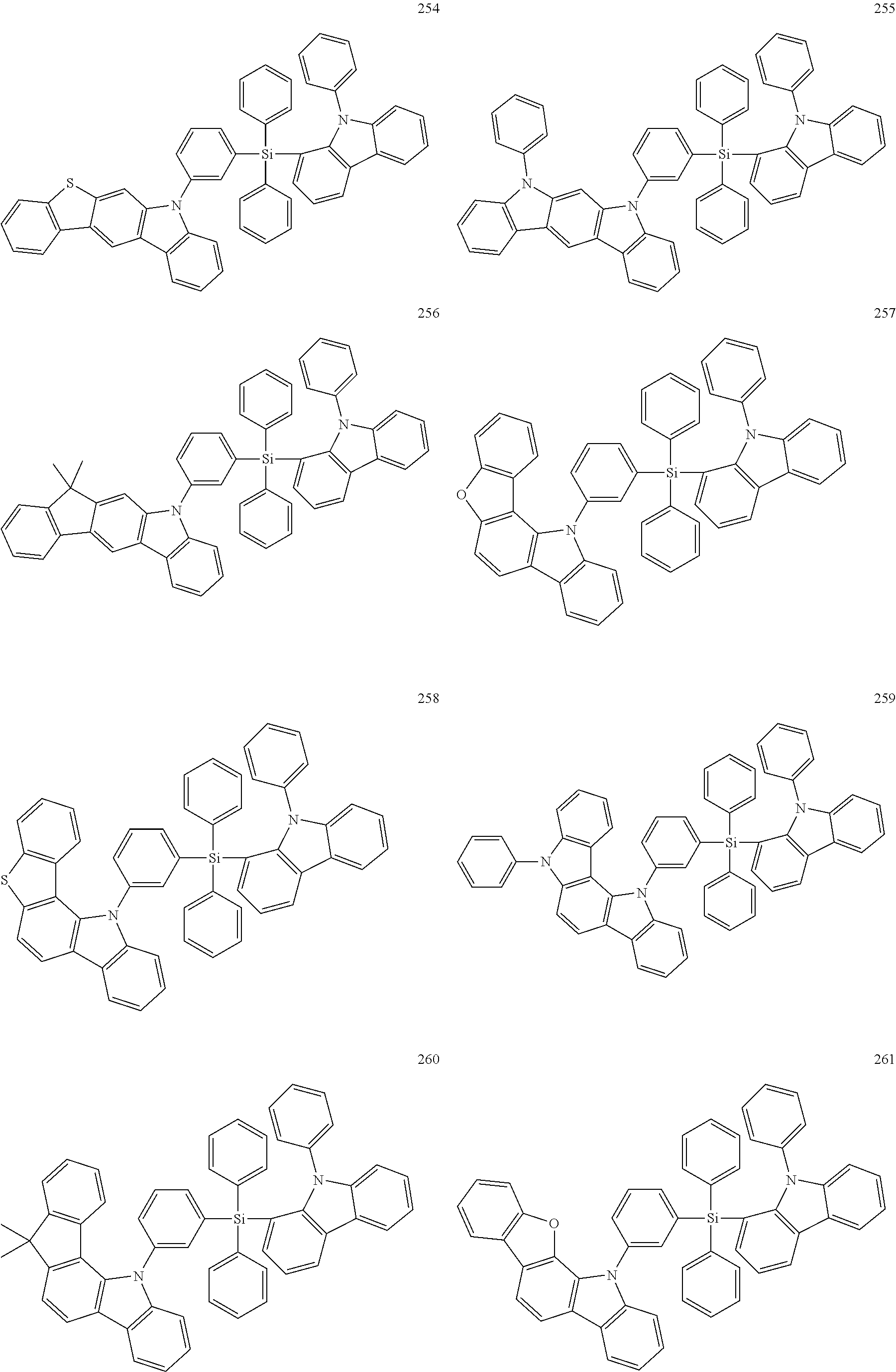

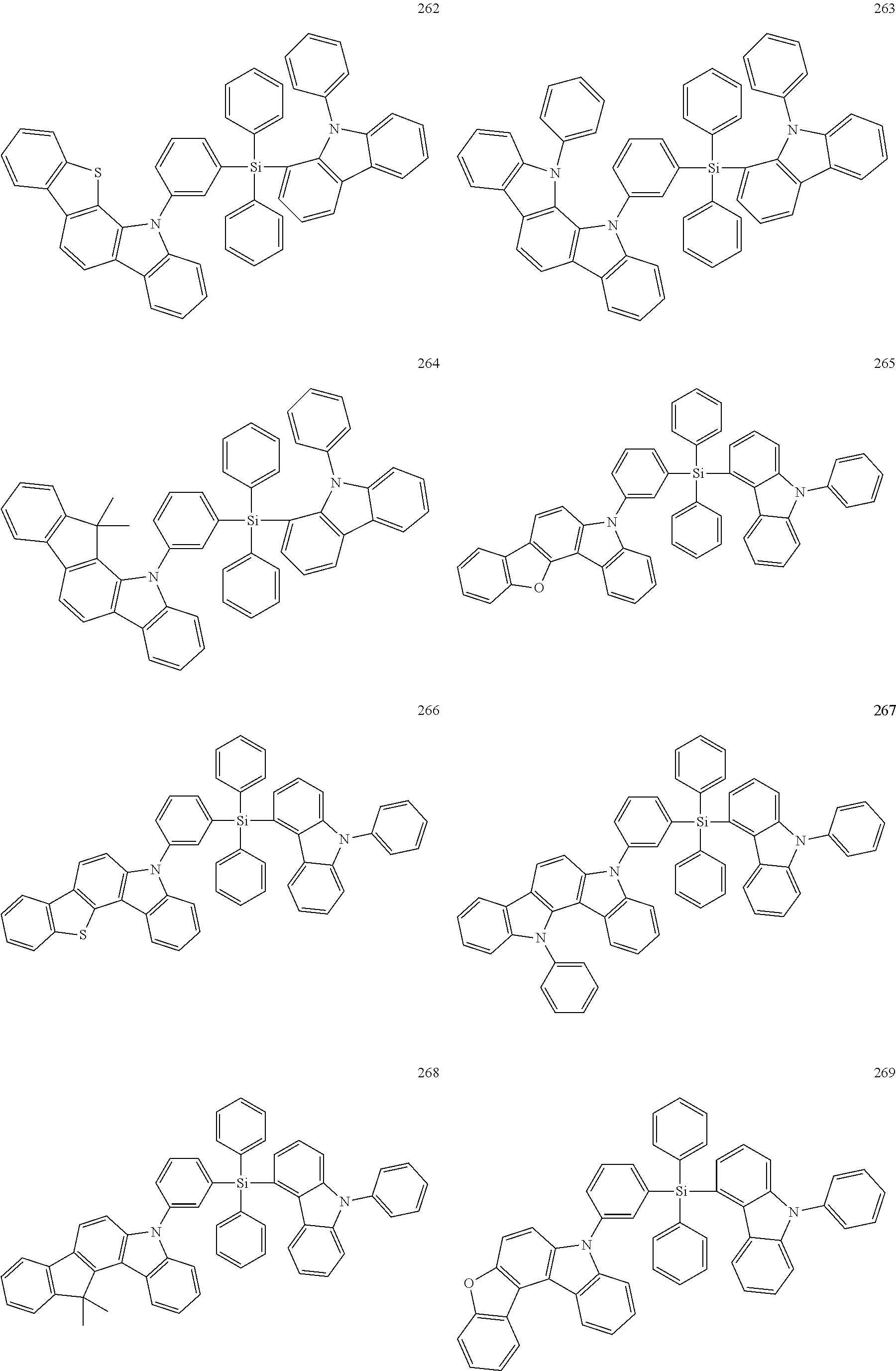

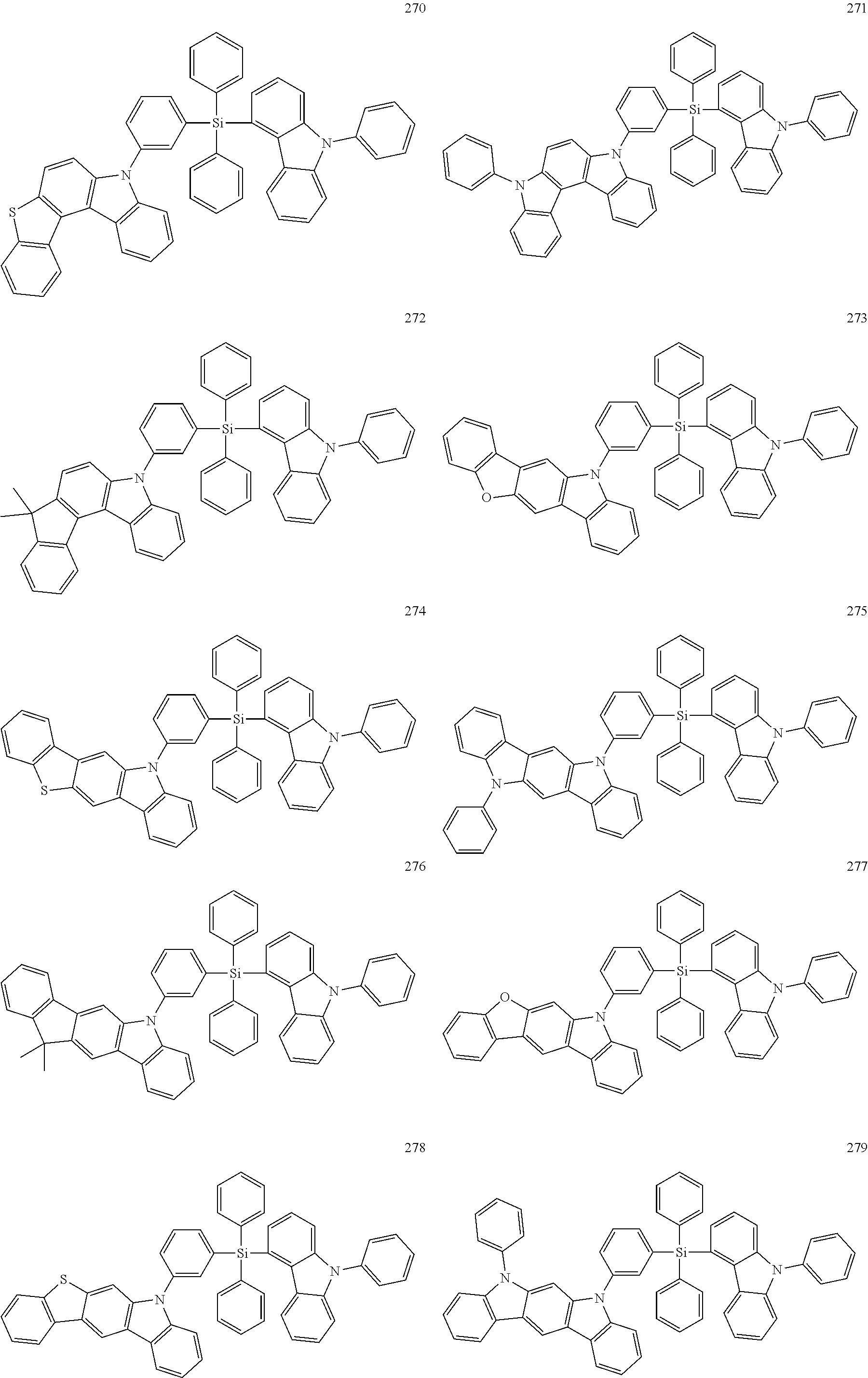

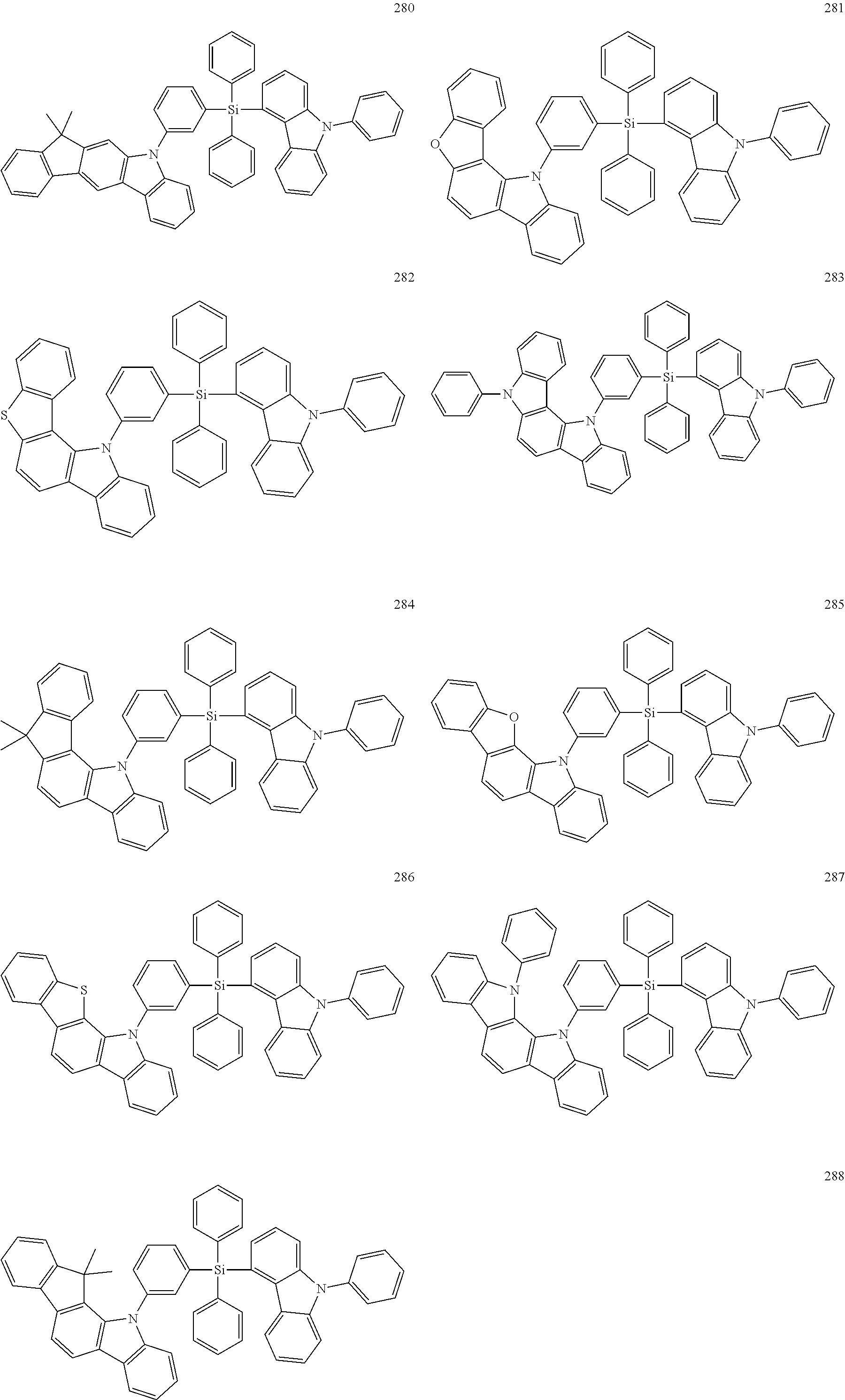

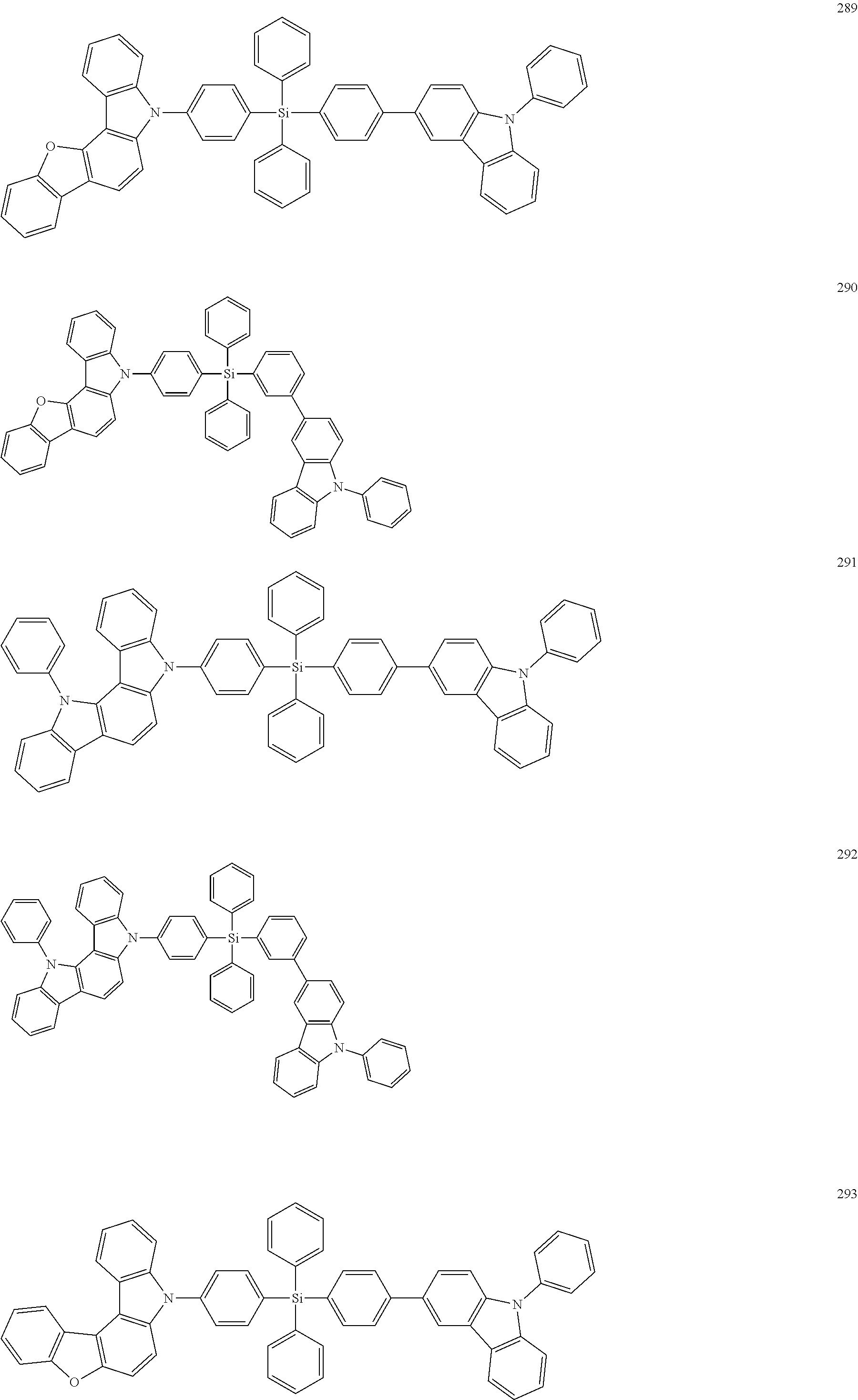

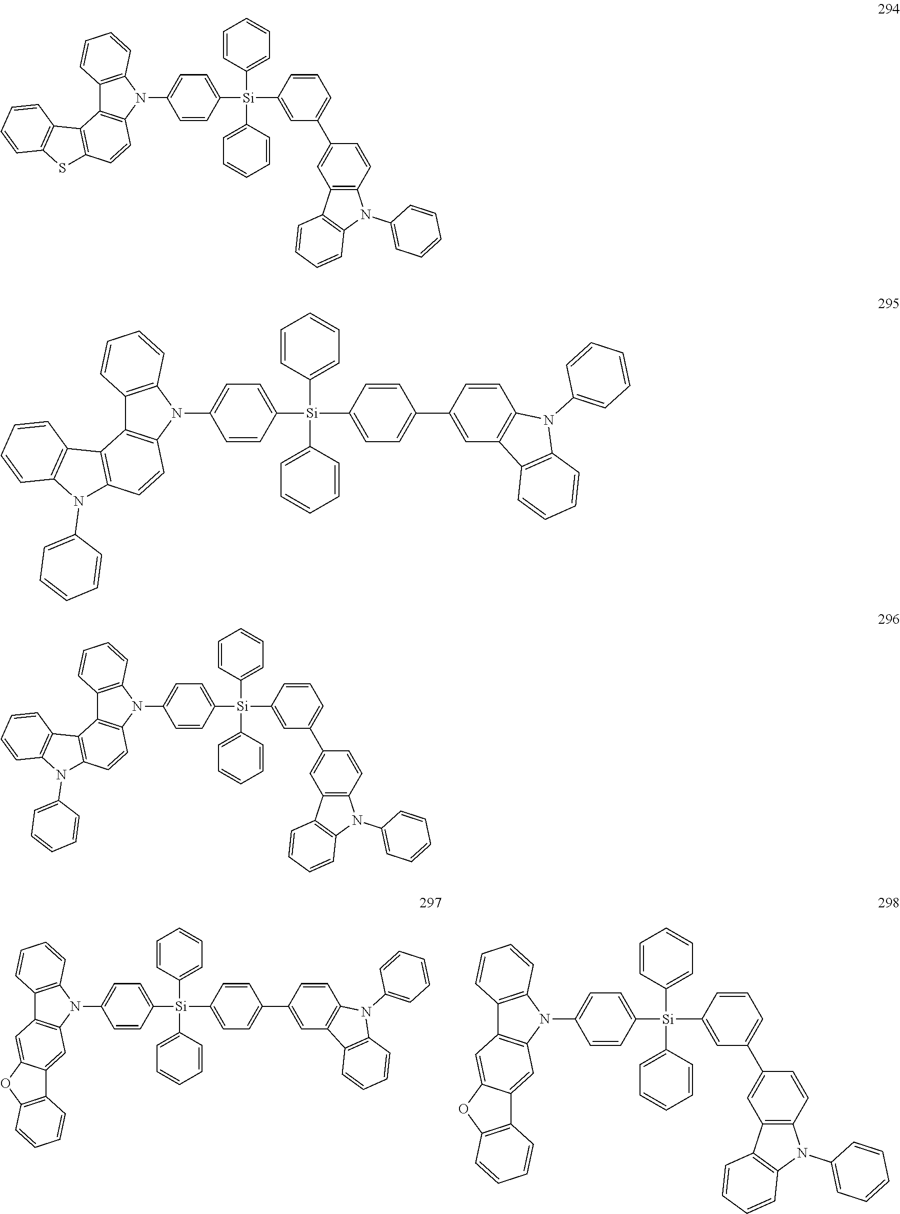

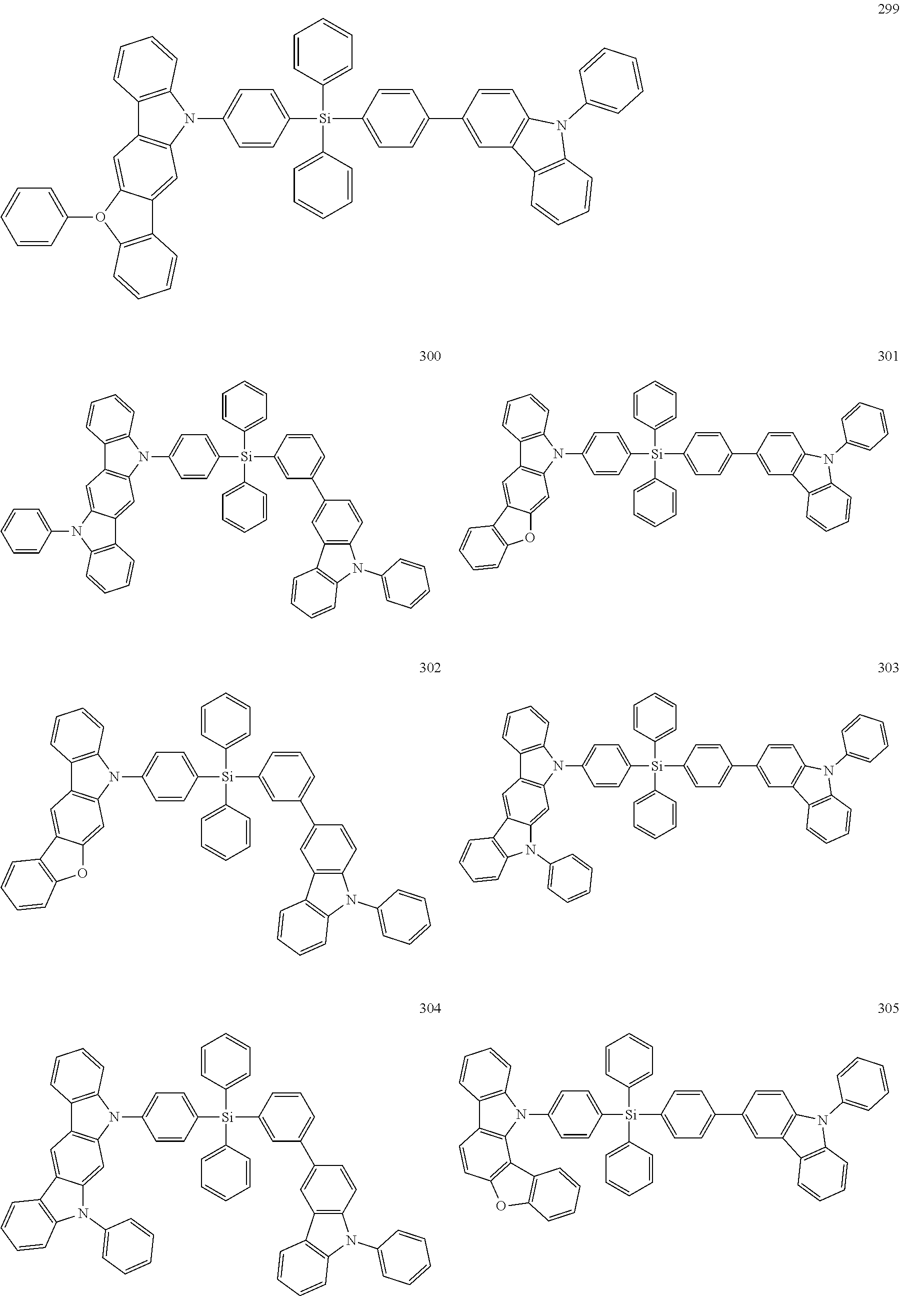

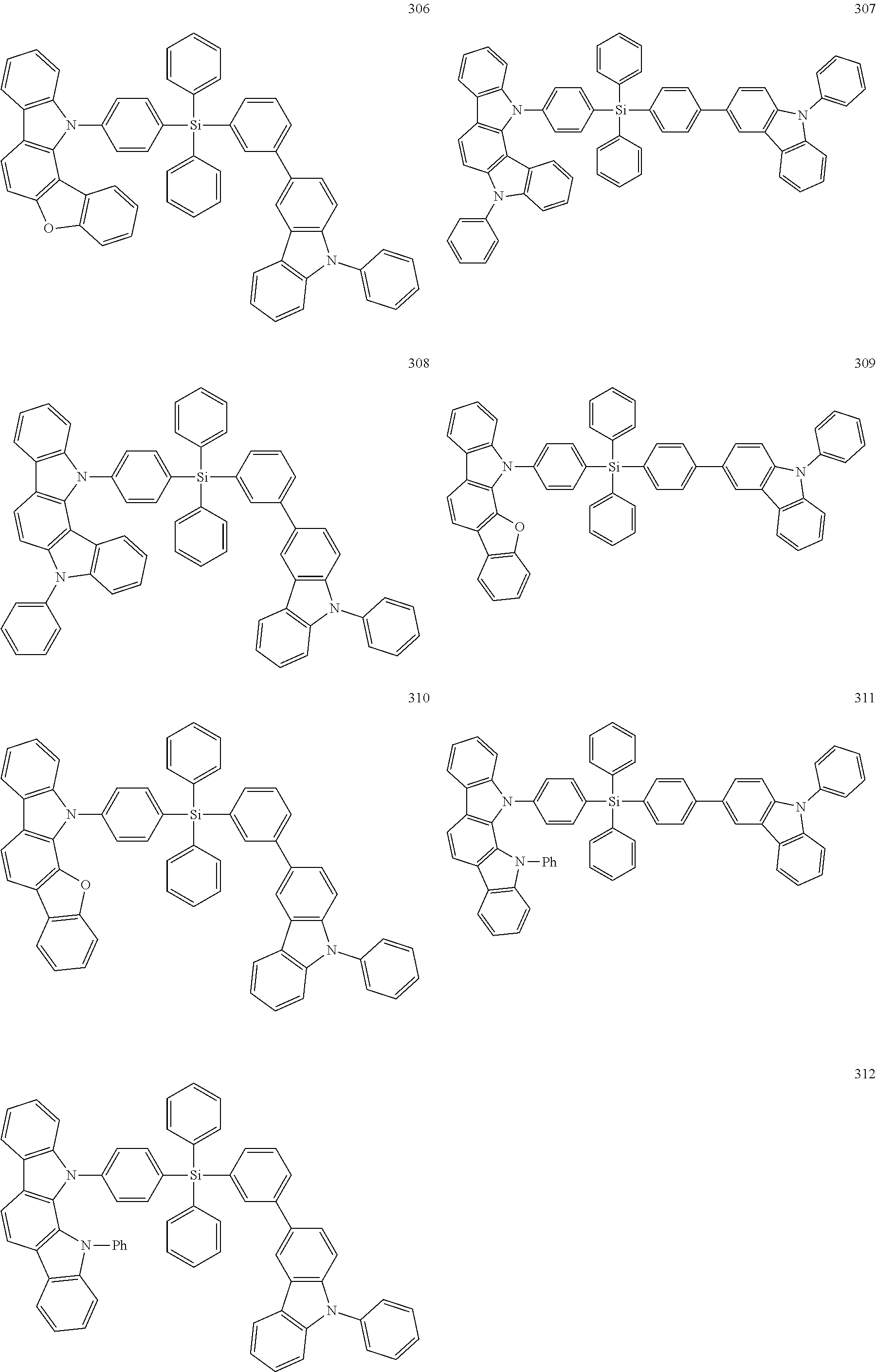

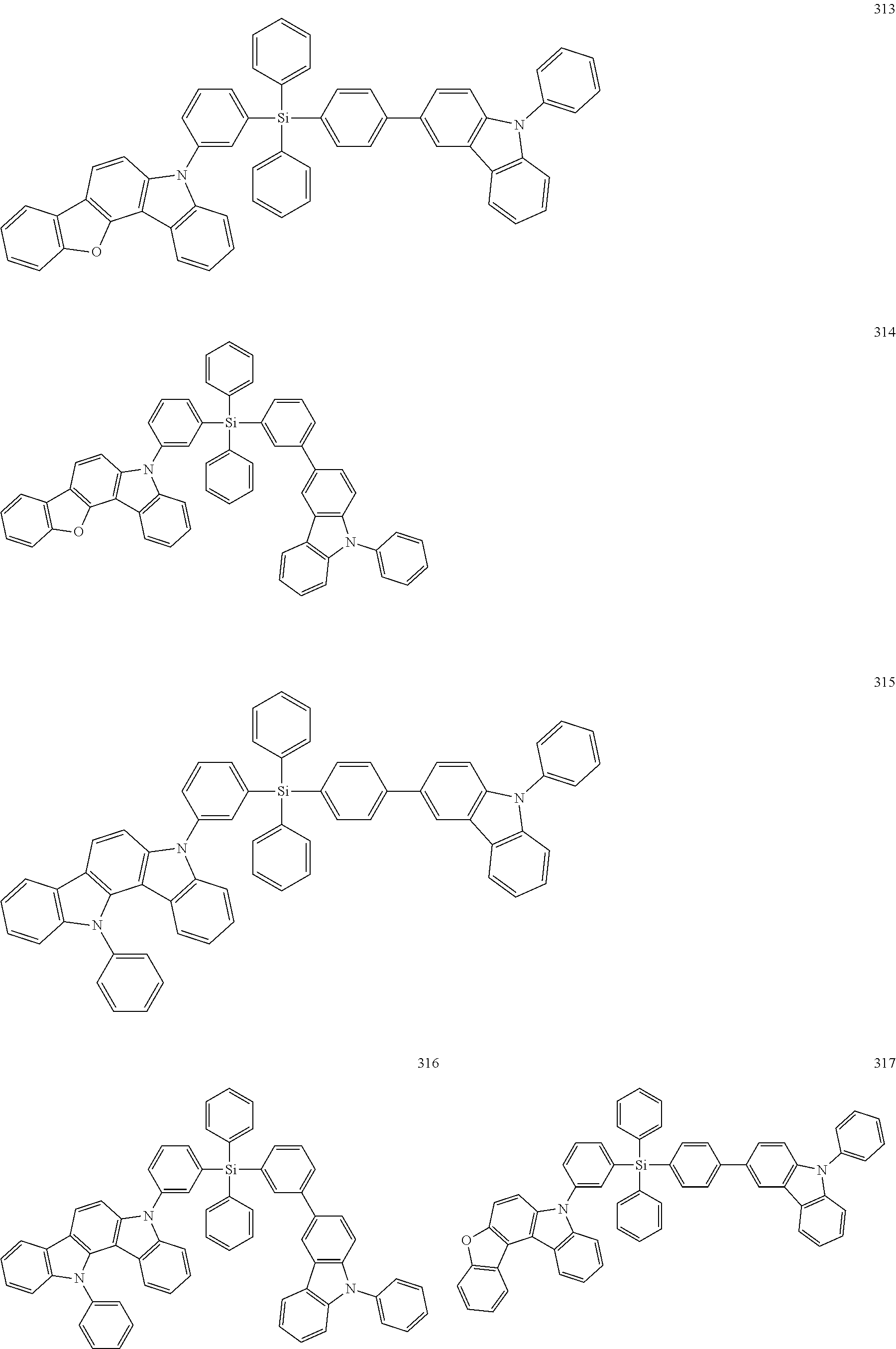

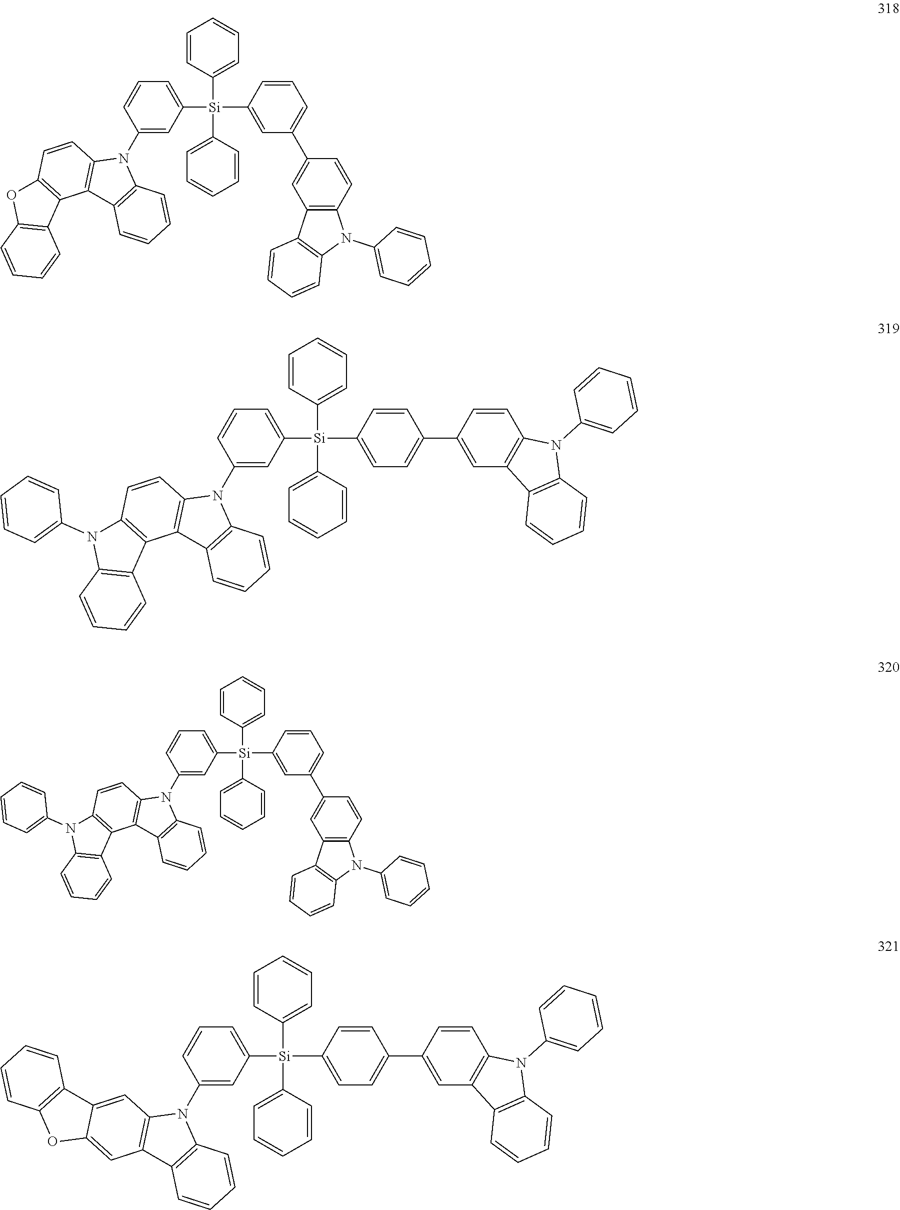

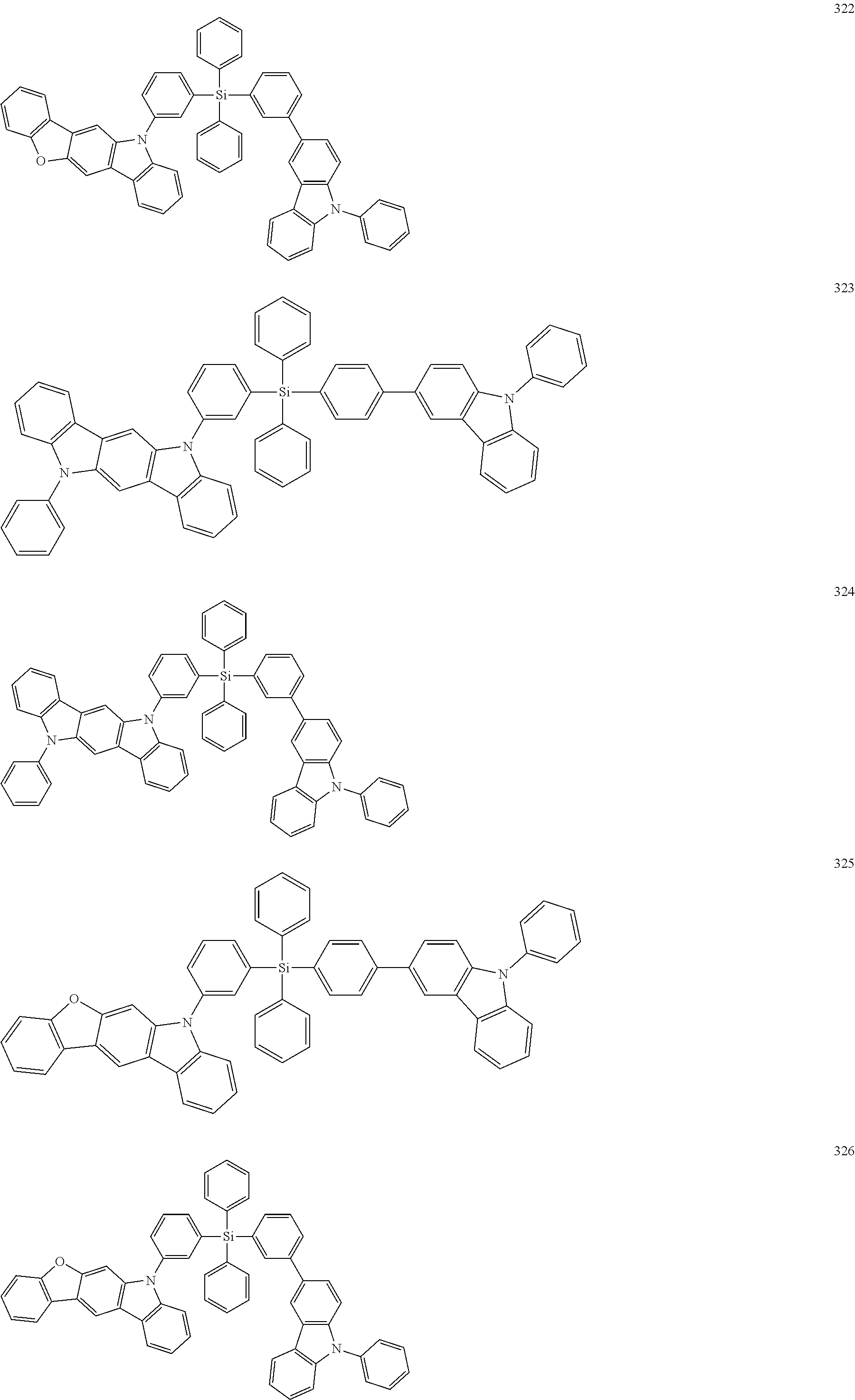

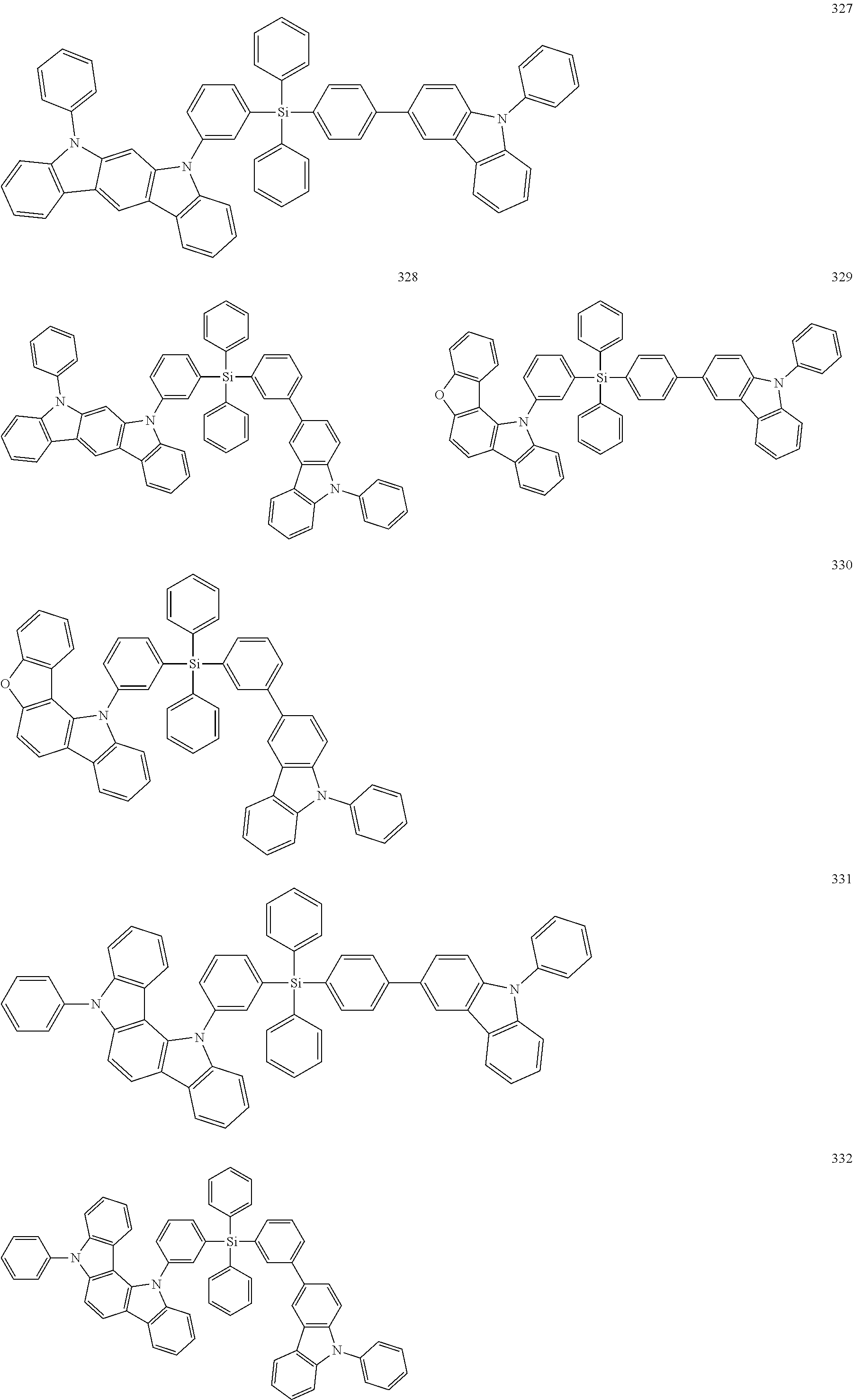

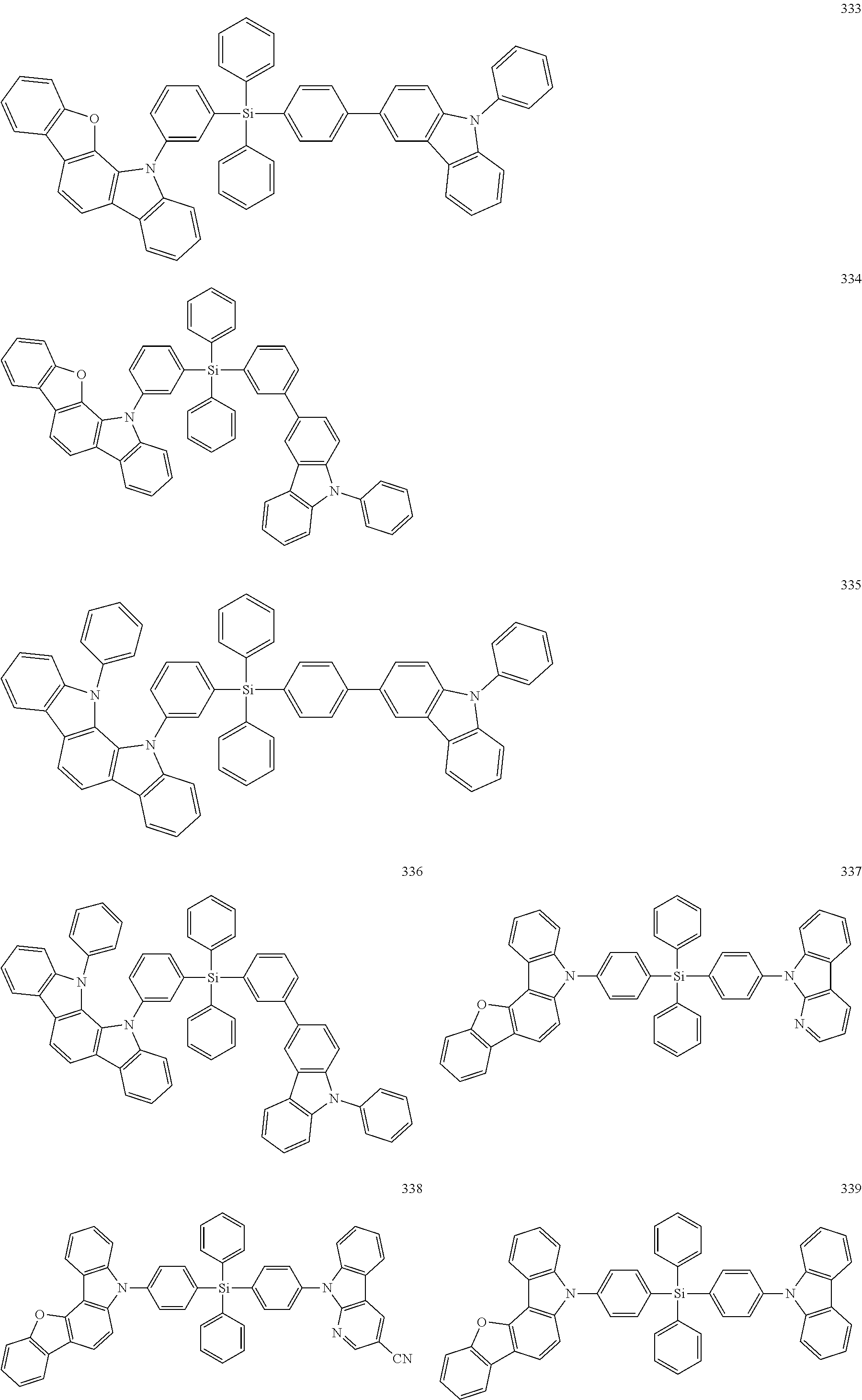

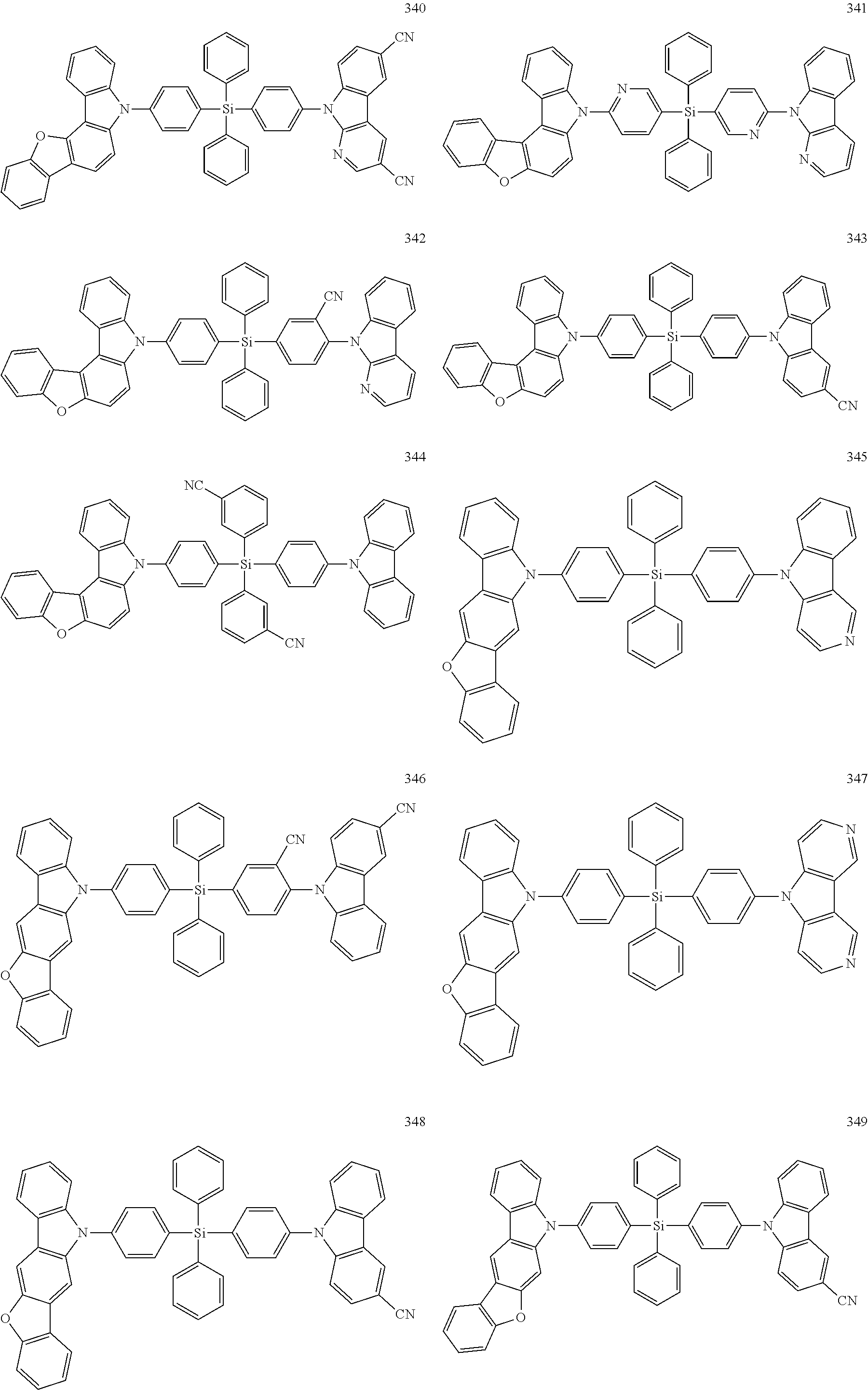

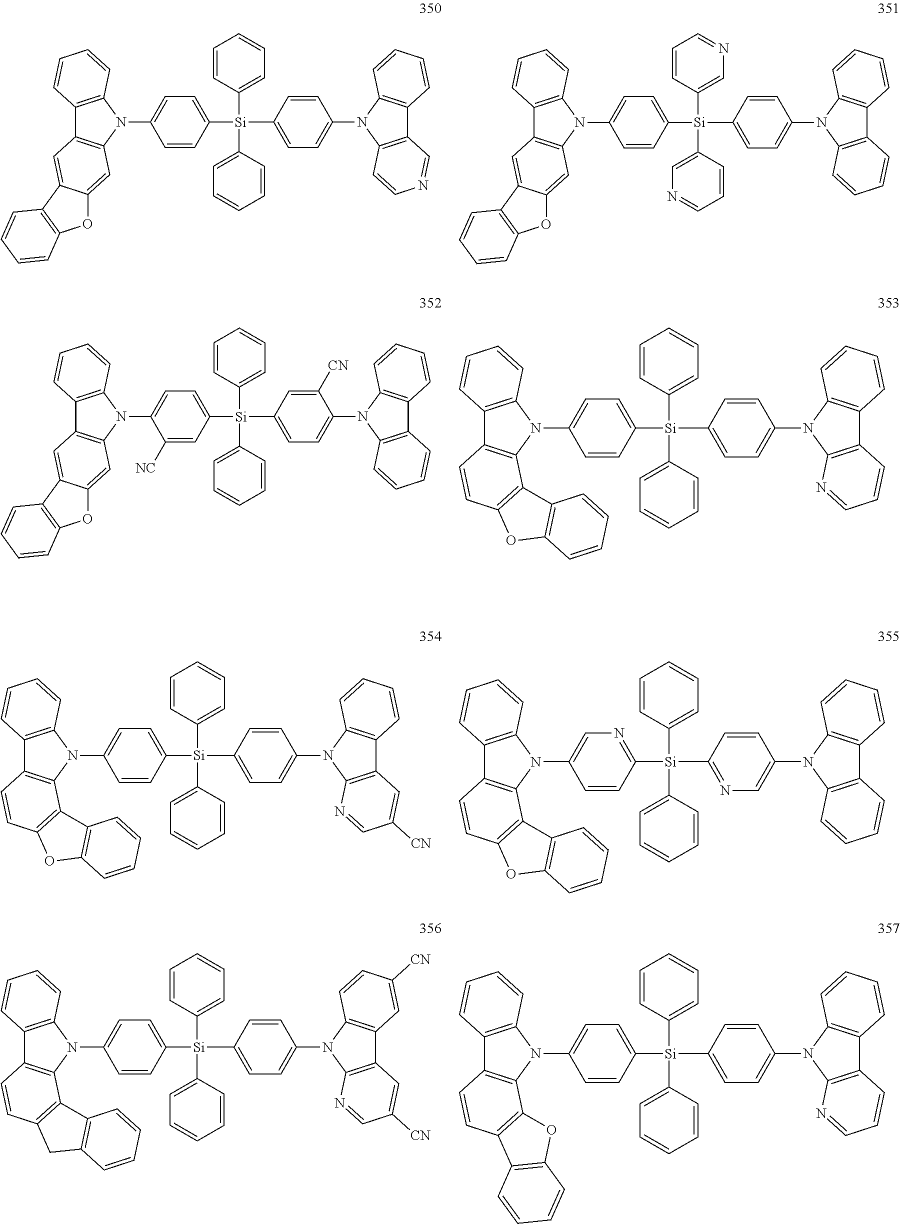

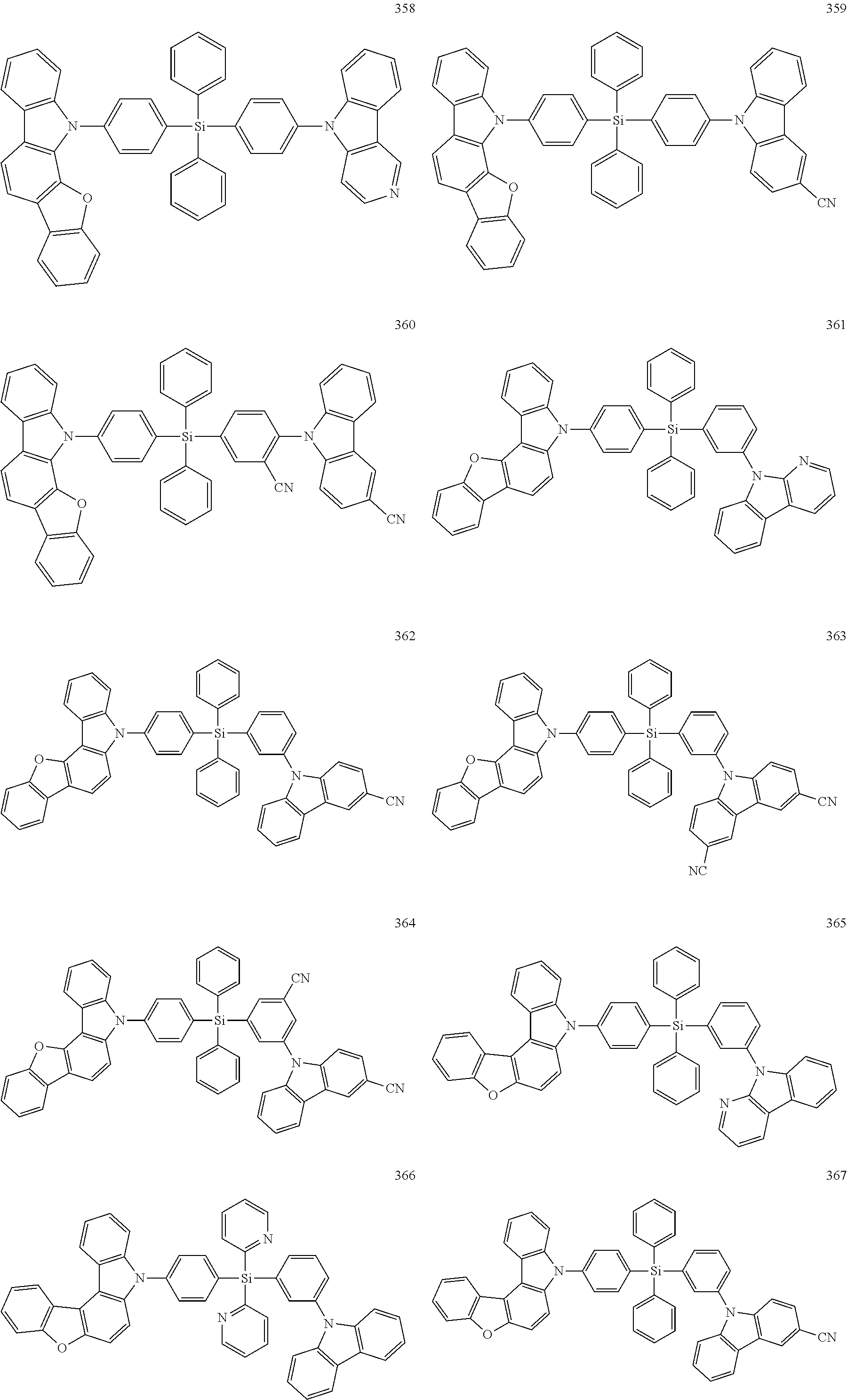

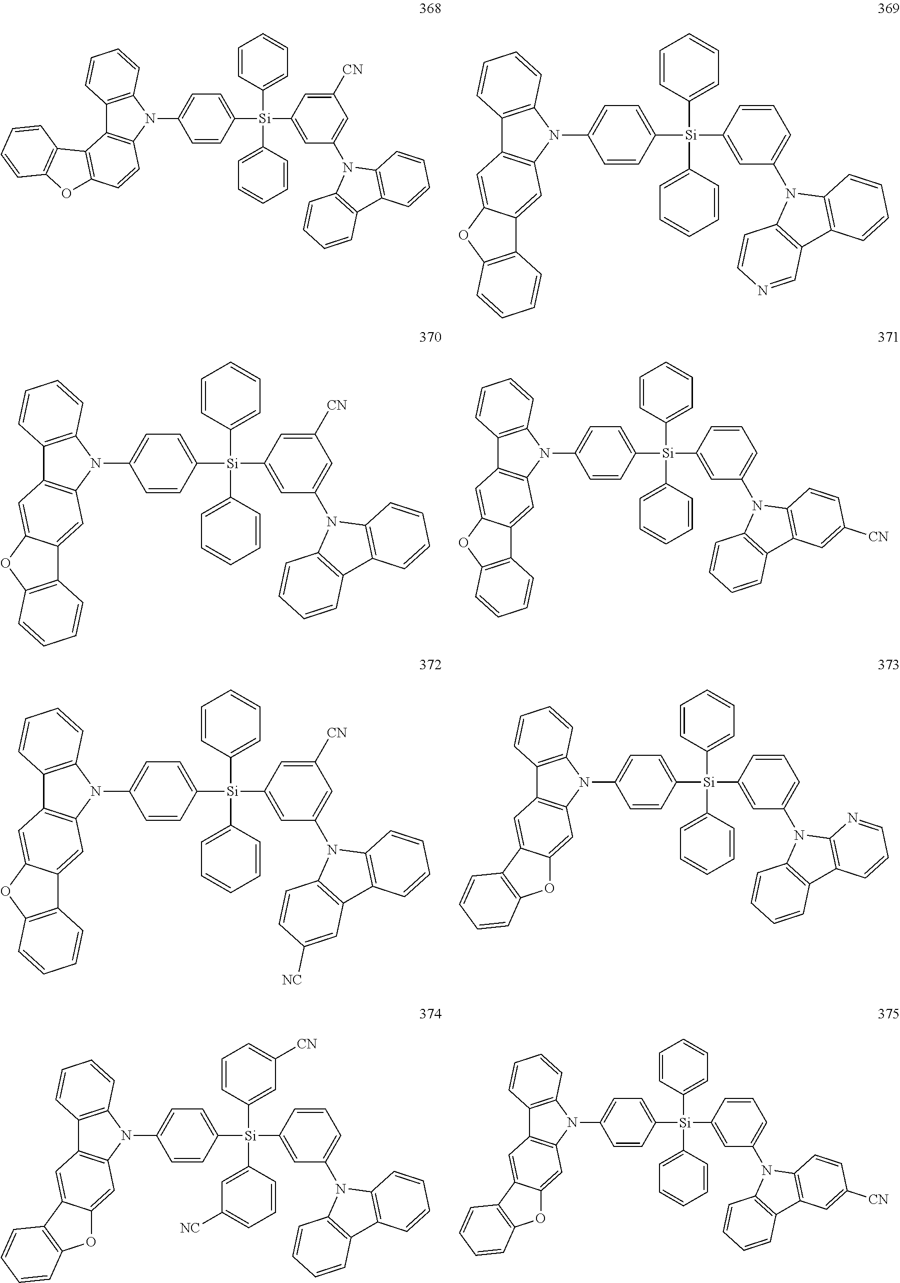

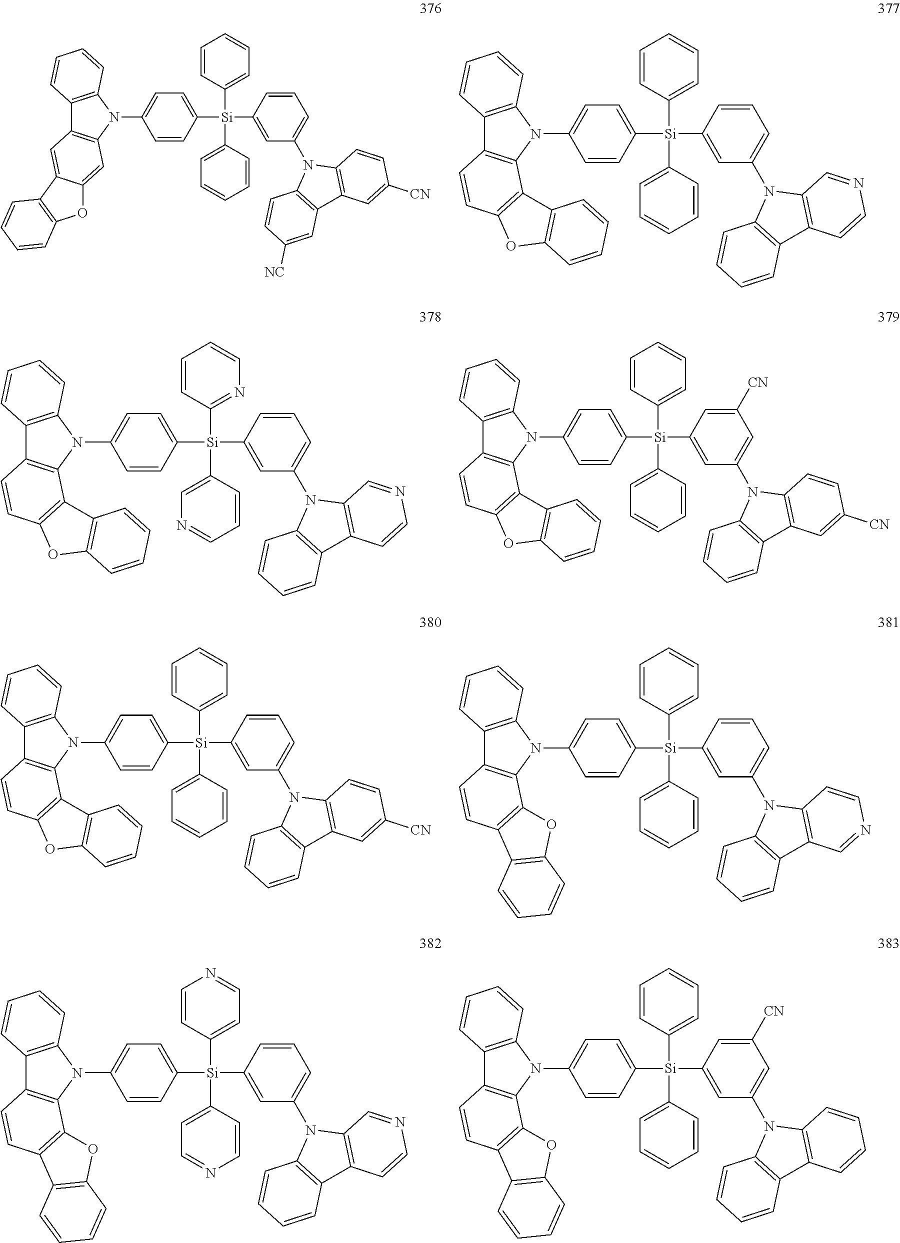

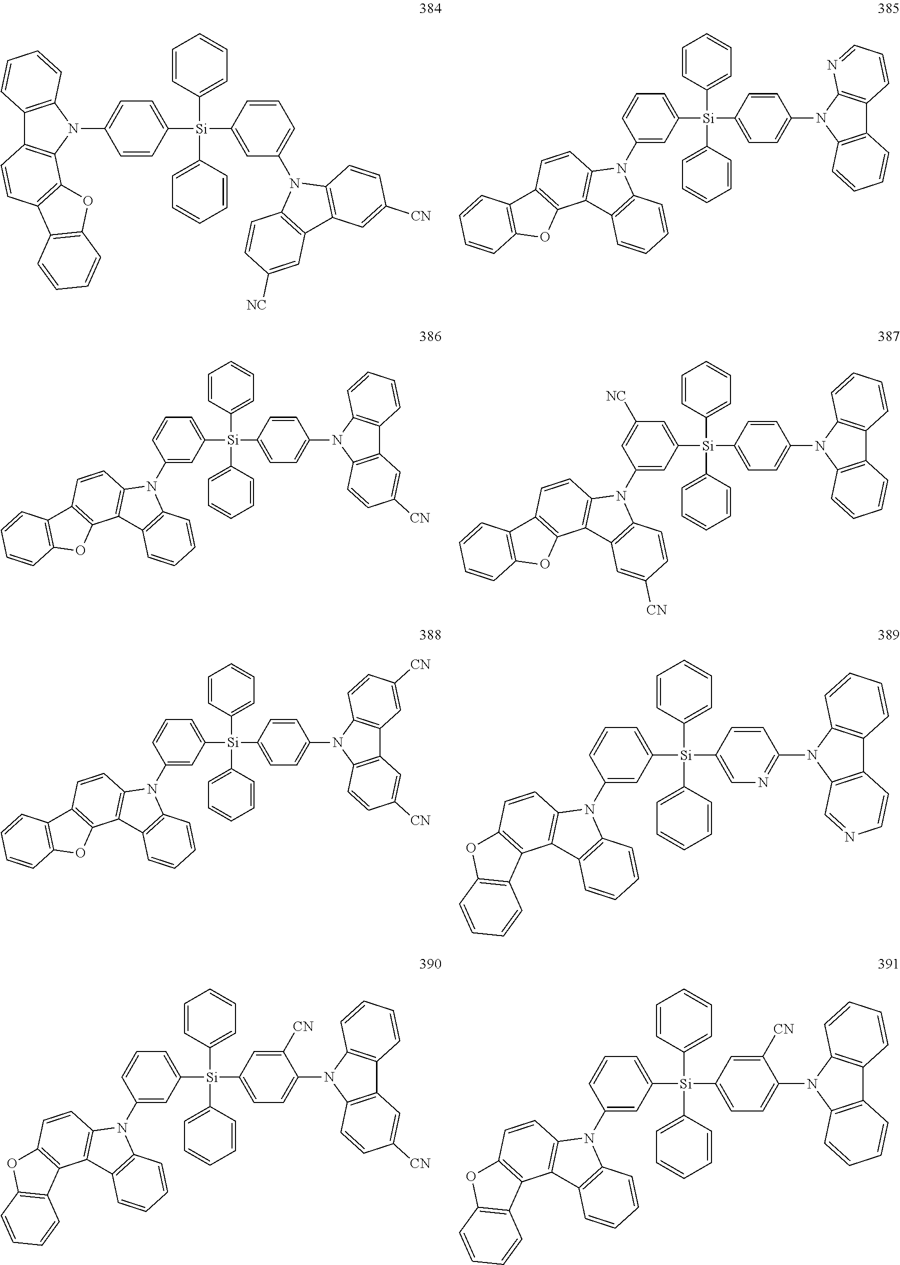

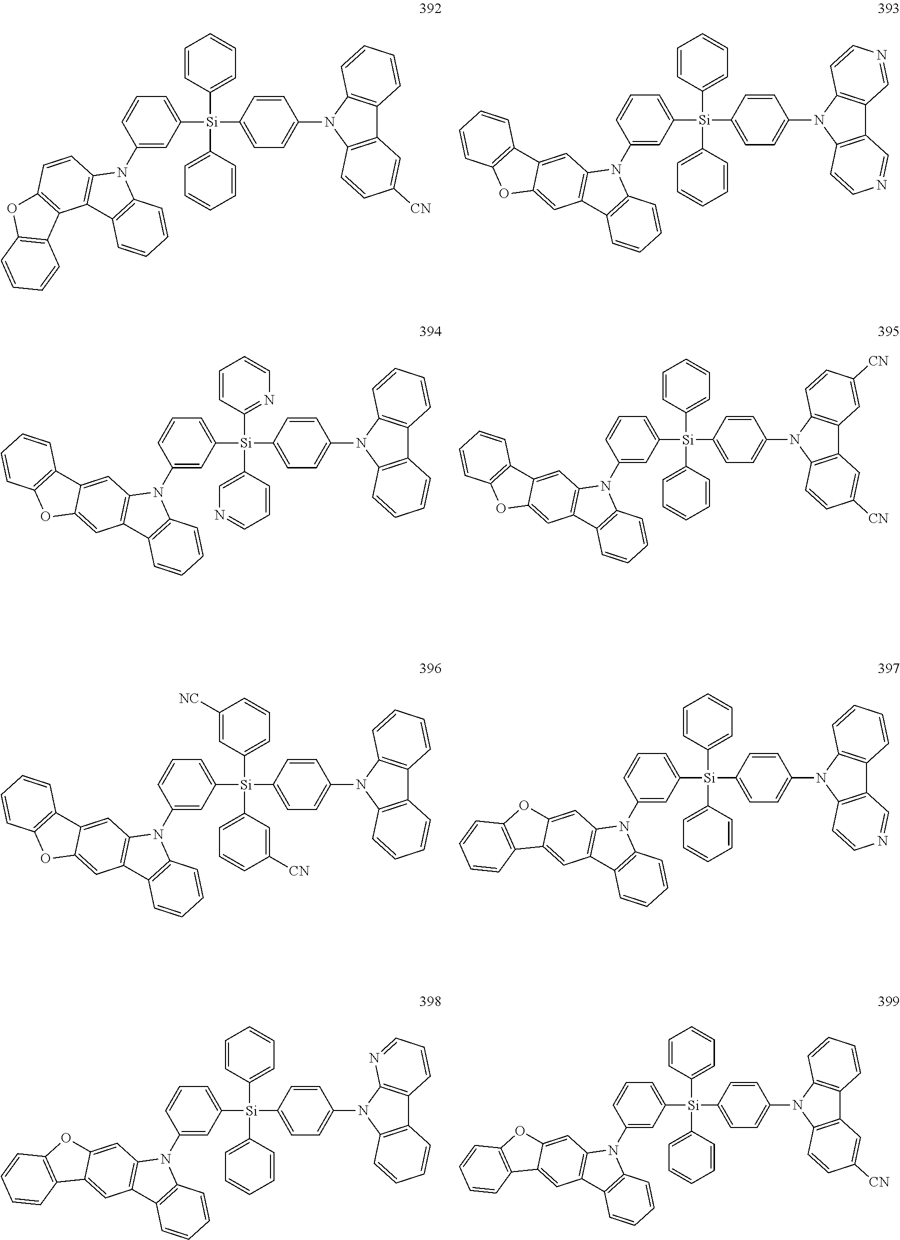

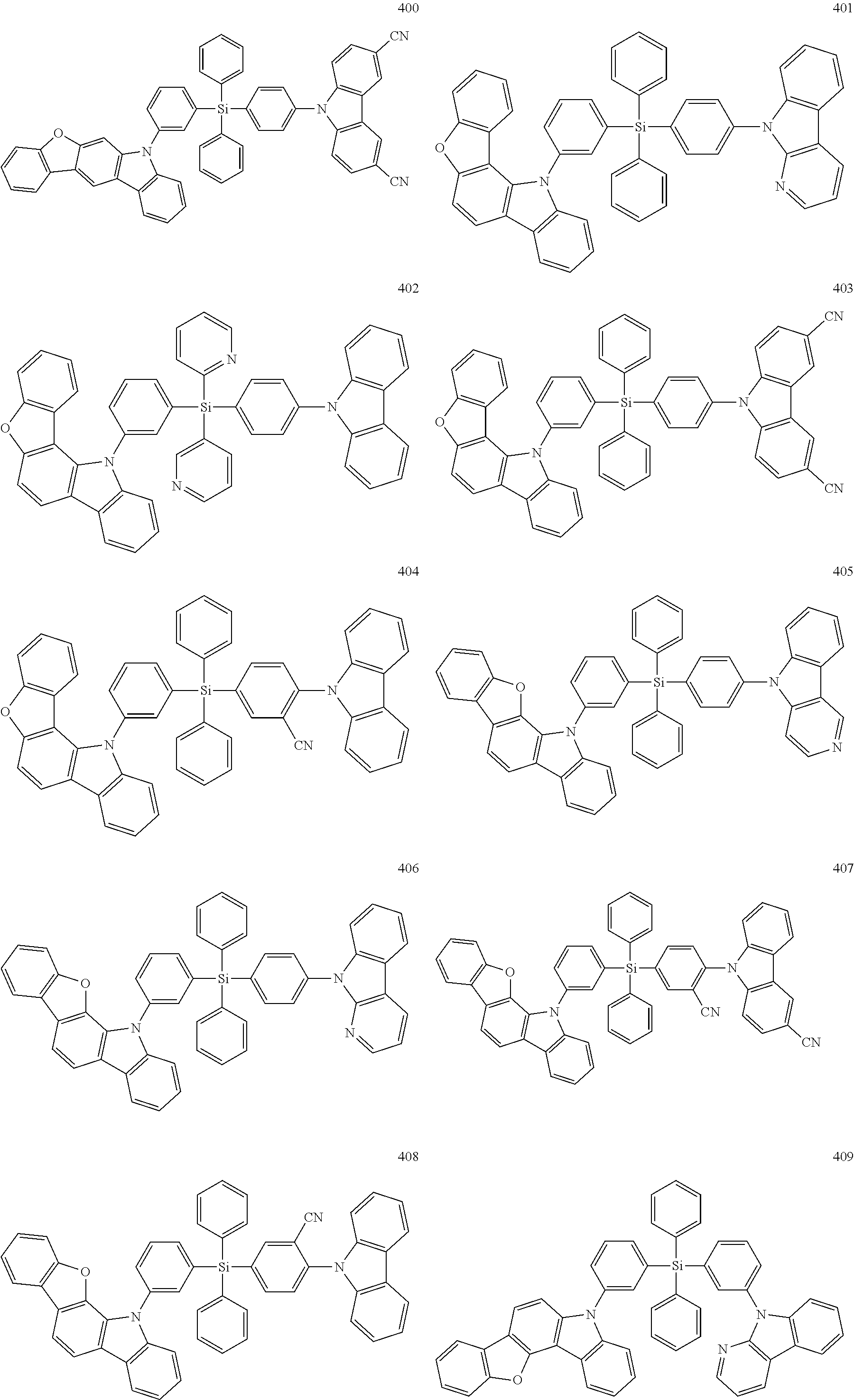

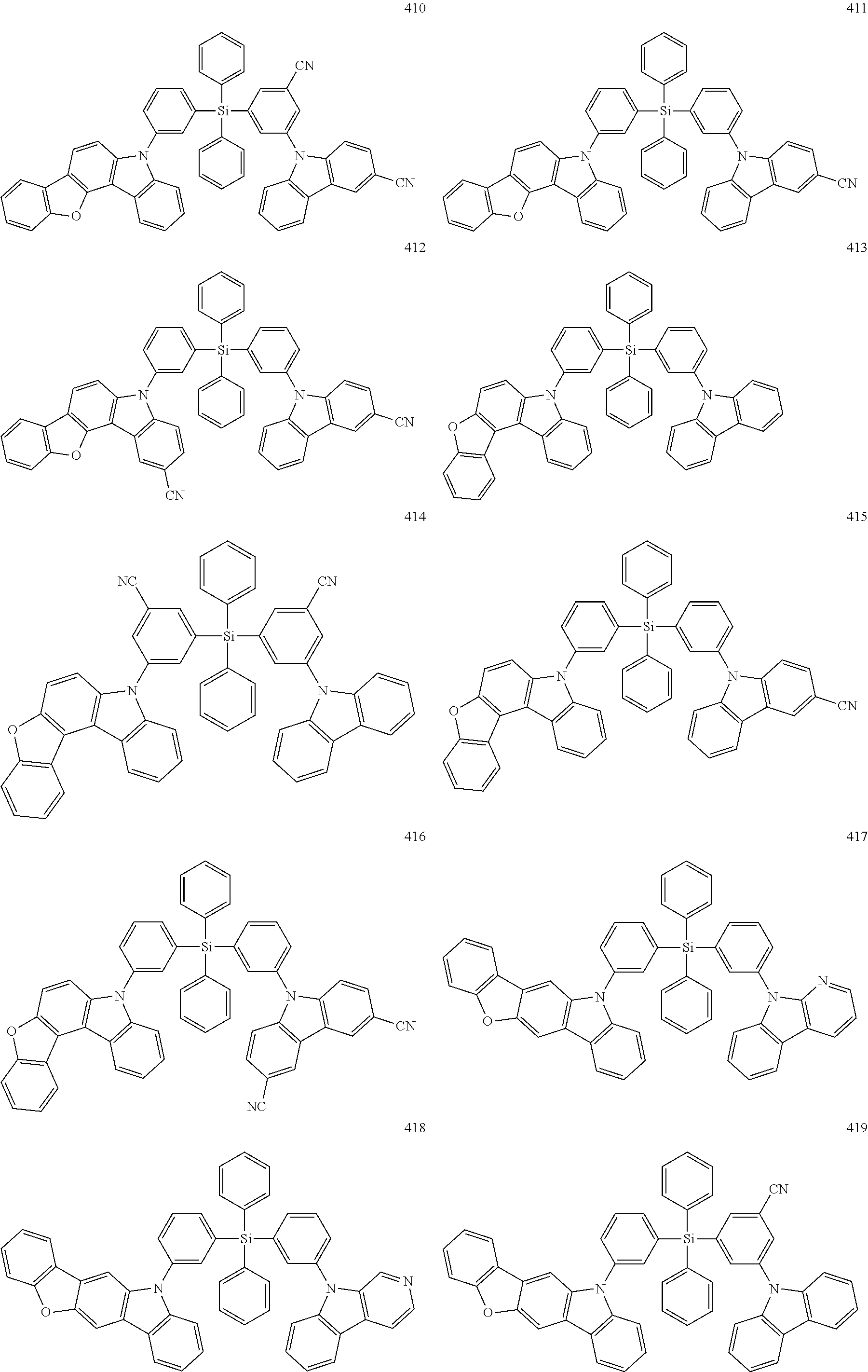

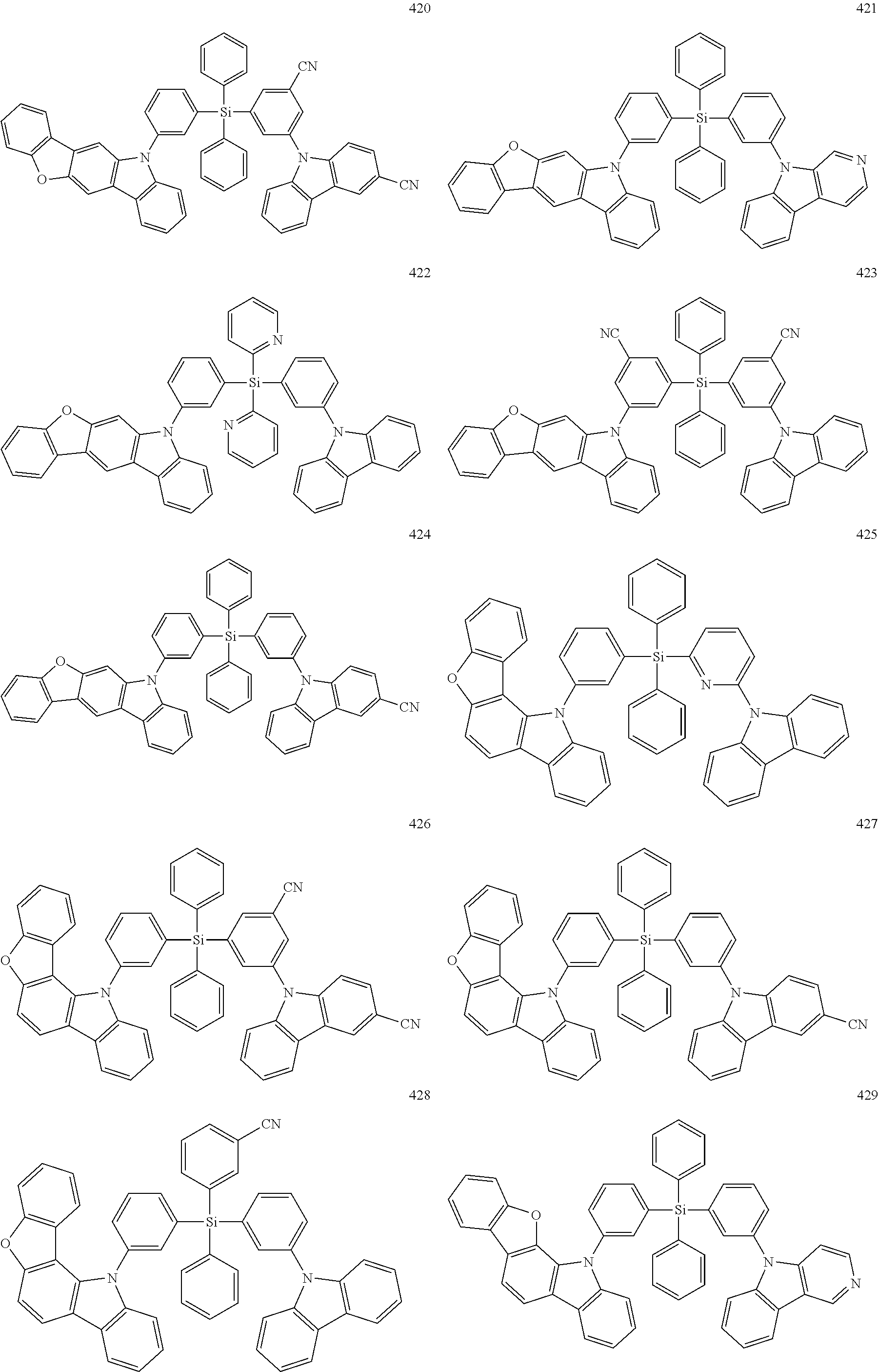

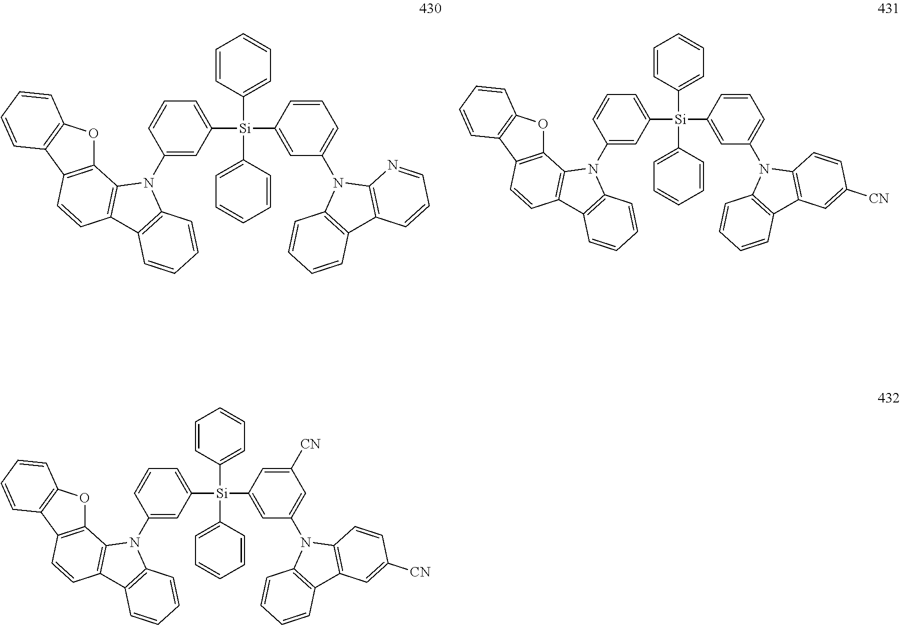

wherein, in Compounds 1 to 432,

Ph may be a phenyl group.

When the host is a mixture of an electron transport host and a hole transport host, the weight ratio of the electron transport host and hole transport host may be 1:9 to 9:1, for example, 2:8 to 8:2, for example, 4:6 to 6:4, for example, 5:5. When the weight ratio of the electron transport host and the hole transport host satisfies the above-described ranges, the hole-and-electron transport balance in the emission layer may be made.

In one or more embodiments, the host may include at least one of TPBi, TBADN, ADN (also referred to as “DNA”), CBP, CDBP, TCP, mCP, or Compound H50 to Compound H52:

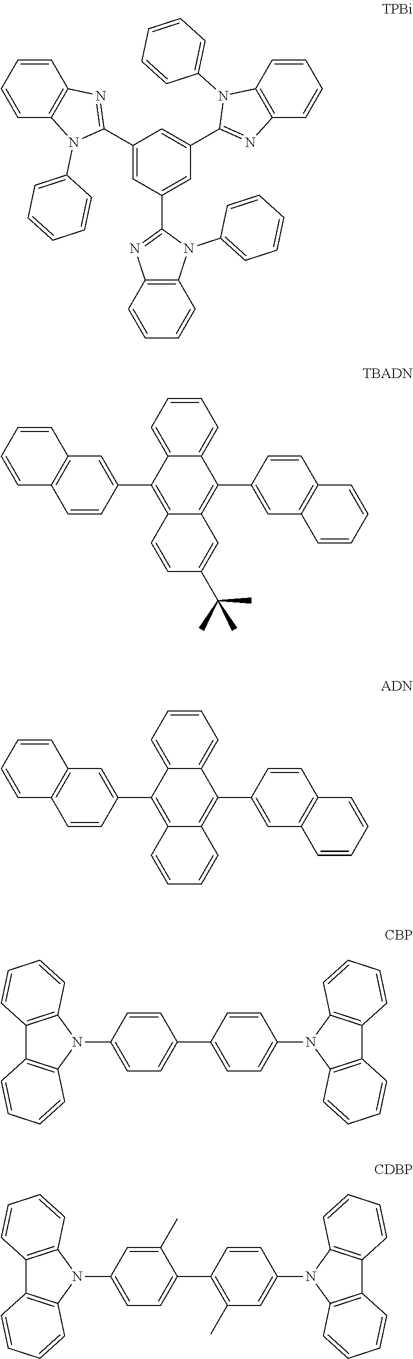

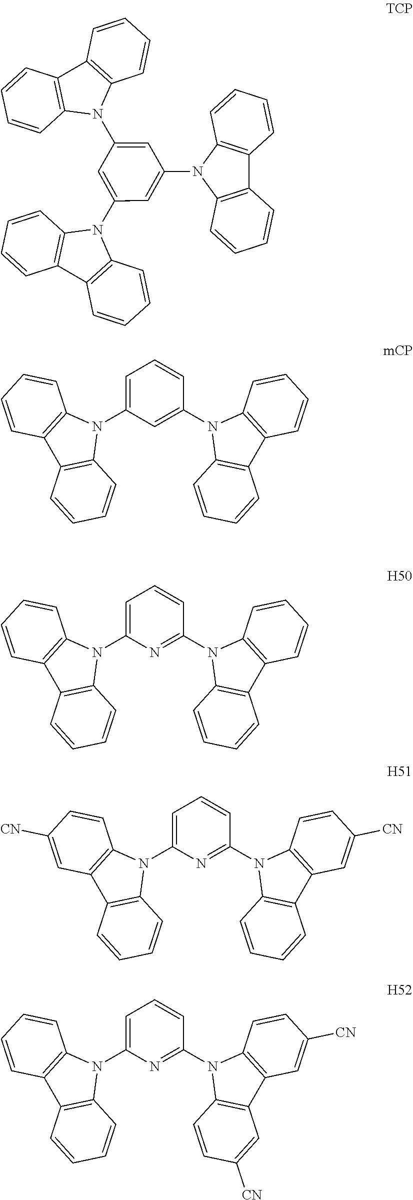

In one or more embodiments, the host may further include a compound represented b Formula 301:

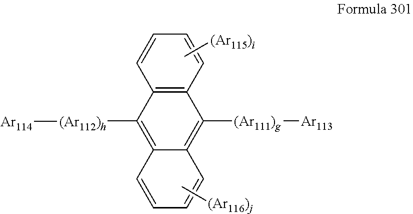

wherein, Ar₁₁₁ and Ar₁₁₂ in Formula 301 may each independently be:

a phenylene group, a naphthylene group, a phenanthrenylene group, or a pyrenylene group; or

a phenylene group, a naphthylene group, a phenanthrenylene group, or a pyrenylene group, each substituted with at least one of a phenyl group, a naphthyl group, or an anthracenyl group.

Ar₁₁₃ to Ar₁₁₆ in Formula 301 may each independently be:

a C₁-C₁₀ alkyl group, a phenyl group, a naphthyl group, a phenanthrenyl group, or a pyrenyl group; or

a phenyl group, a naphthyl group, a phenanthrenyl group, or a pyrenyl group, each substituted with at least one of a phenyl group, a naphthyl group, or an anthracenyl group.

g, h, i, and j in Formula 301 may each independently be an integer from 0 to 4, and may be, for example, 0, 1, or 2.

Ar₁₁₃ and Ar₁₁₅ in Formula 301 may each independently be:

a C₁-C₁₀ alkyl group, substituted with at least one of a phenyl group, a naphthyl group, or an anthracenyl group;

a phenyl group, a naphthyl group, an anthracenyl group, a pyrenyl, a phenanthrenyl group, or a fluorenyl group:

a phenyl group, a naphthyl group, an anthracenyl group, a pyrenyl group, a phenanthrenyl group, or a fluorenyl group, each substituted with at least one of deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₂-C₆₀ alkoxy group, a phenyl group, a naphthyl group, an anthracenyl group, a pyrenyl group, a phenanthrenyl group, or a fluorenyl group; or

a group of the formula:

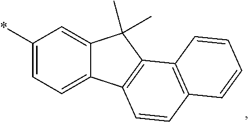 [SMILES: *c1ccc2c(c1)C(C)(C)c1c-2ccc2ccccc12]

but embodiments of the present disclosure are not limited thereto.

In one or more embodiments, the host may include a compound represented by Formula 302:

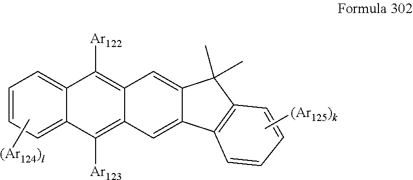

Ar₁₂₂ to Ar₁₂₅ in Formula 302 are the same as described in connection with Arm in Formula 301.

Ar₁₂₆ and Ar₁₂₇ in Formula 302 may each independently be a C₁-C₁₀ alkyl group (for example, a methyl group, an ethyl group, or a propyl group).

k and l in Formula 302 may each independently be an integer from 0 to 4. For example, k and l may be 0, 1, or 2.

When the organic light-emitting device is a full-color organic light-emitting device, the emission layer may be patterned into a red emission layer, a green emission layer, and a blue emission layer. In one or more embodiments, due to a stacked structure including a red emission layer, a green emission layer, and/or a blue emission layer, the emission layer may emit white light.

When the emission layer includes a host and a light-emitting dopant, an amount of the light-emitting dopant may be in a range of about 0.01 parts by weight to about 15 parts by weight based on 100 parts by weight of the host, but embodiments of the present disclosure are not limited thereto.

A thickness of the emission layer may be in a range of about 100 Å to about 1,000 Å, for example, about 200 Å to about 600 Å. When the thickness of the emission layer is within these ranges, excellent light-emission characteristics may be obtained without a substantial increase in driving voltage.

The light-emitting dopant may include the polycyclic compound represented by Formula 1.

In one or more embodiments, the sensitizer may include metal (M₁₁) of at least one of a first-row transition metal of the Periodic Table of Elements, a second-row transition metal of the Periodic Table of Elements, or a third-row transition metal of the Periodic Table of Elements, and an organic ligand L₁, and L₂ and M₁₁ may form 1, 2, 3, or 4 cyclometallated rings.

In one or more embodiments, the sensitizer may include an organometallic compound represented by Formula 101:

M₁₁(L₁)ₙ₁(L₂)ₙ₂. Formula 101

wherein, in Formula 101,

M₁₁ is a first-row transition metal of the Periodic Table of Elements, a second-row transition metal of the Periodic Table of Elements, or a third-row transition metal of the Periodic Table of Elements;

L₁ is a ligand represented by one of Formulae 10-1 to 10-4:

L₂ may be a monodentate ligand or a bidentate ligand;

n1 may be 1;

n2 is 0, 1, or 2;

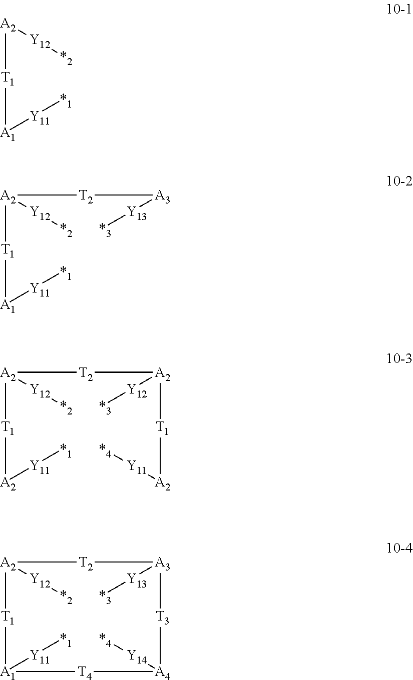

wherein, in Formulae 10-1 to 10-4,

A₁ to A₄ may each independently be a substituted or unsubstituted C₅-C₃₀ carbocyclic group, a substituted or unsubstituted C₁-C₃₀ heterocyclic group, or a non-cyclic group,

Y₁₁ to Y₁₄ may each independently be a chemical bond, O, S, N(R₉₁), B(R₉₁), P(R₉₁), or C(R₉₁)(R₉₂),

T₁ to T₄ may each independently be a single bond, a double bond, —N(R₉₃)—, —B(R₉₃)—, —P(R₉₃)′, —C(R₉₃)(R₉₄)—, —Si(R₉₃)(R₉₄)—, —Ge(R₉₃)(R₉₄)′, —S—, —Se—, —O′, —C(═O)—, —S(═O)—, —S(═O)₂—, —C(R₉₃)═, ═C(R₉₃)—, —C(R₉₃)═C(R₉₄)—, —C(═S)—, or —C≡C—,

at least one substituent of the substituted C₅-C₃₀ carbocyclic group, a substituent of substituted C₁-C₃₀ heterocyclic group, and R₉₁ to R₉₄ may each independently be hydrogen, deuterium, —F, —Cl, —Br, —I, —SF₅, a hydroxyl group, a cyano group, a nitro group, an amidino group, a hydrazine group, a hydrazone group, a carboxylic acid or a salt thereof, a sulfonic acid or a salt thereof, a phosphoric acid or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₇-C₆₀ alkyl aryl group, a substituted or unsubstituted C₇-C₆₀ aryl alkyl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted C₁-C₆₀ heteroaryloxy group, a substituted or unsubstituted C₁-C₆₀ heteroarylthio group, a substituted or unsubstituted C₂-C₆₀ heteroarylalkyl group, a substituted or unsubstituted monovalent non-aromatic condensed polycyclic group, a substituted or unsubstituted monovalent non-aromatic condensed heteropolycyclic group, —Si(Q₁)(Q₂)(Q₃), —B(Q₁)(Q₂), —N(Q₁)(Q₂), —P(Q₁)(Q₂), —C(═O)(Q₁), —S(═O)(Q₁), —S(═O)₂(Q₁), —P(═O)(Q₁)(Q₂), or —P(═S)(Q₁)(Q₂), wherein each of a substituent of the substituted C₅-C₃₀ carbocyclic group and a substituent of substituted C₁-C₃₀ heterocyclic group is not hydrogen,

*1, *2, *3, and *4 each indicate a binding site to M₁₁, and

Q₁ to Q₃ may each independently be hydrogen, deuterium, —F, —Cl, —Br, —I, a hydroxyl group, a cyano group, a nitro group, an amidino group, a hydrazine group, a hydrazone group, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₇-C₆₀ aryl alkyl group, a C₆-C₆₀ aryloxy group, a C₆-C₆₀ arylthio group, a C₁-C₆₀ heteroaryl group, a C₂-C₆₀ alkyl heteroaryl group, a C₁-C₆₀ heteroaryloxy group, a C₁-C₆₀ heteroarylthio group, a C₂-C₆₀ heteroarylalkyl group, a monovalent non-aromatic condensed polycyclic group, a monovalent non-aromatic condensed heteropolycyclic group; a C₁-C₆₀ alkyl group that is substituted with at least one of deuterium, —F, a cyano group, a C₁-C₆₀ alkyl group, or a C₆-C₆₀ aryl group; or a C₆-C₆₀ aryl group that is substituted with at least one of deuterium, —F, a cyano group, a C₁-C₆₀ alkyl group, or a C₆-C₆₀ aryl group.

In one or more embodiments, the sensitizer may be one of Groups I to VI, but embodiments of the present disclosure are not limited thereto:

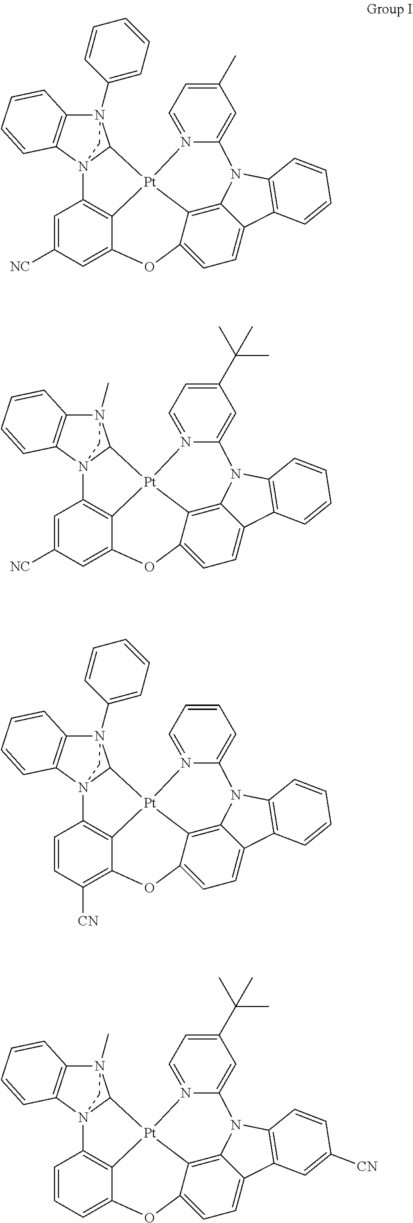

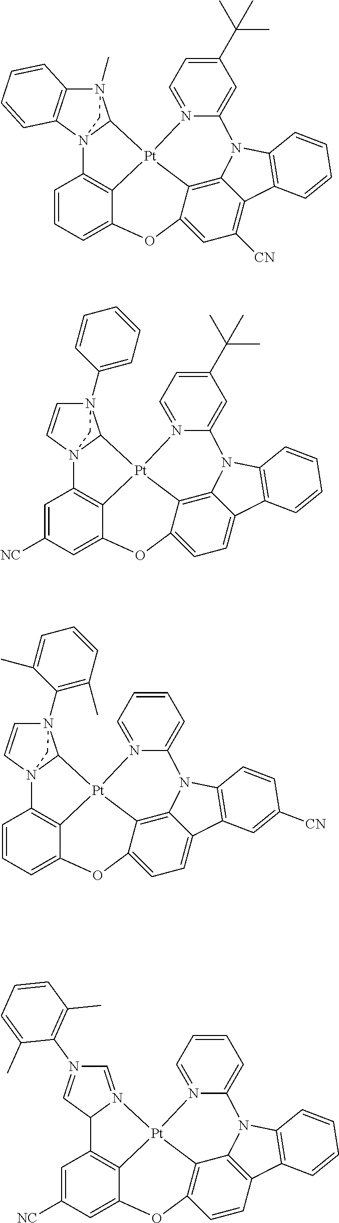

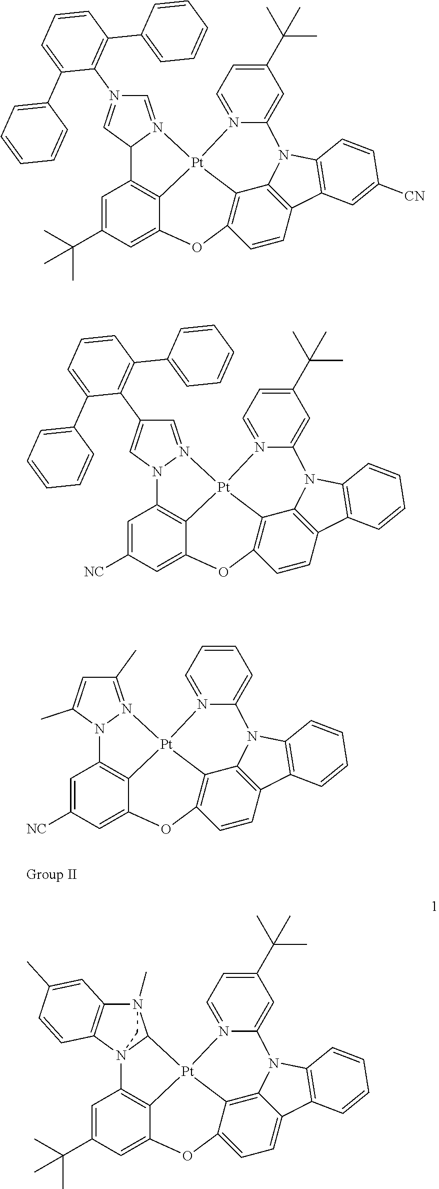

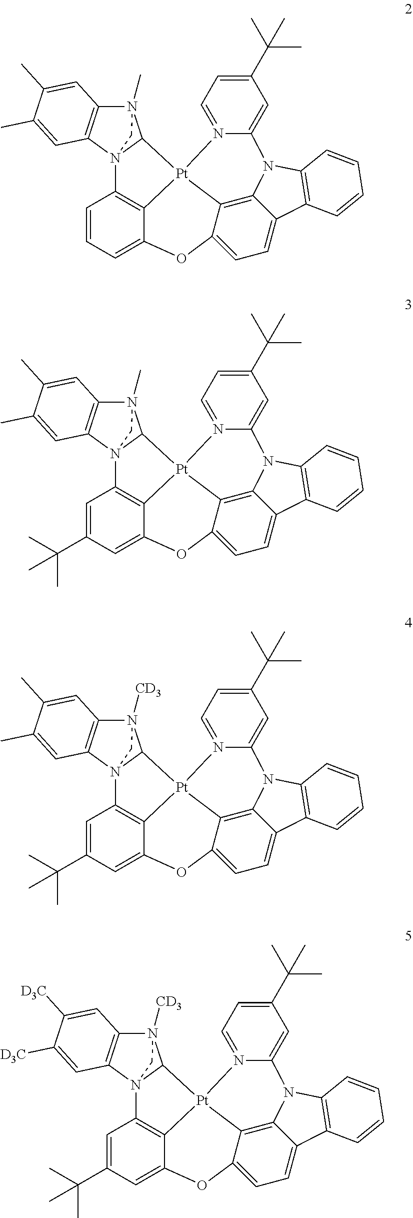

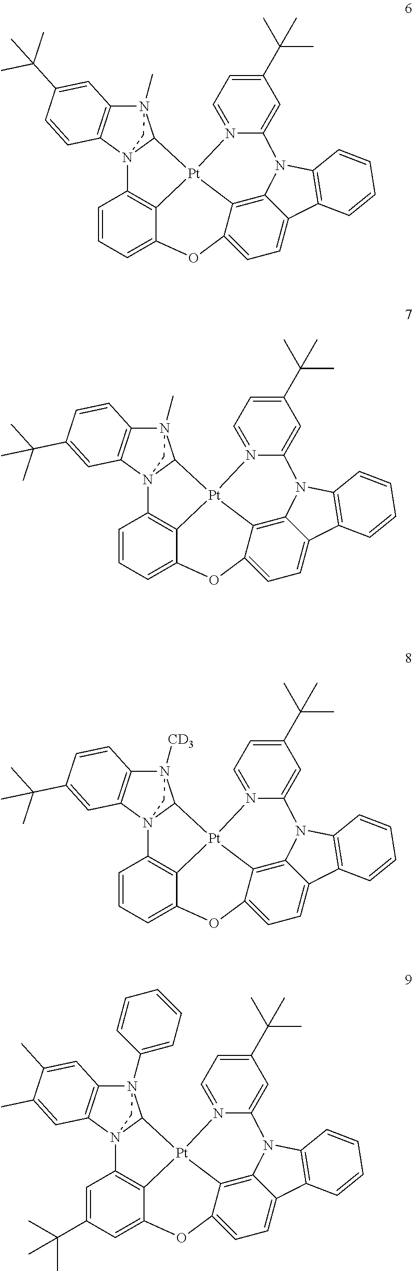

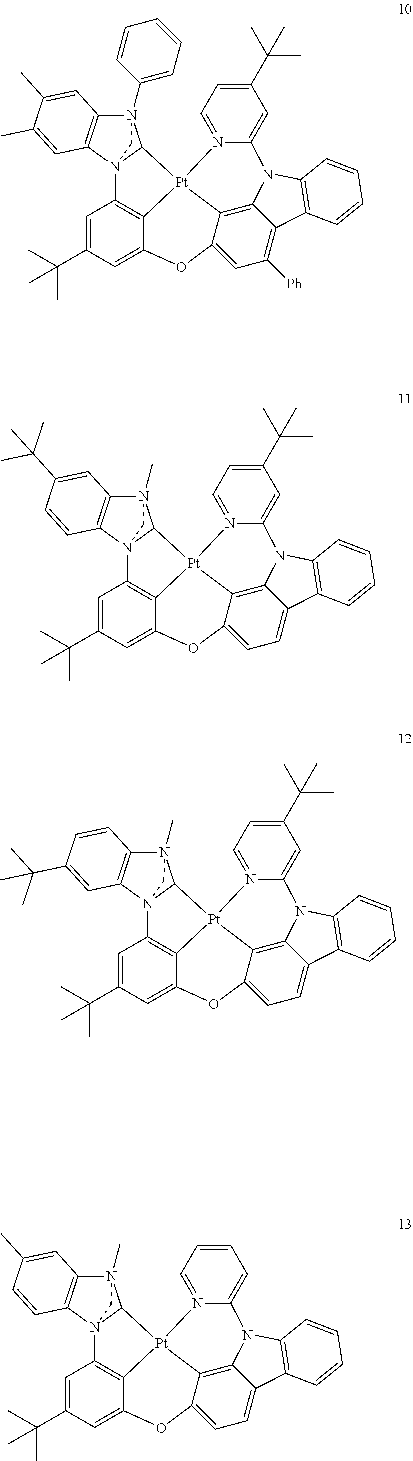

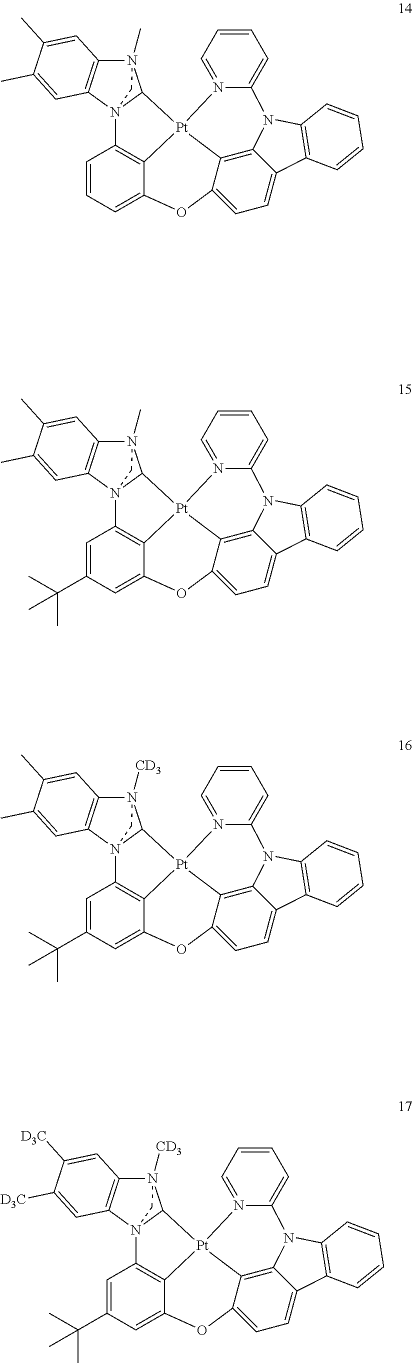

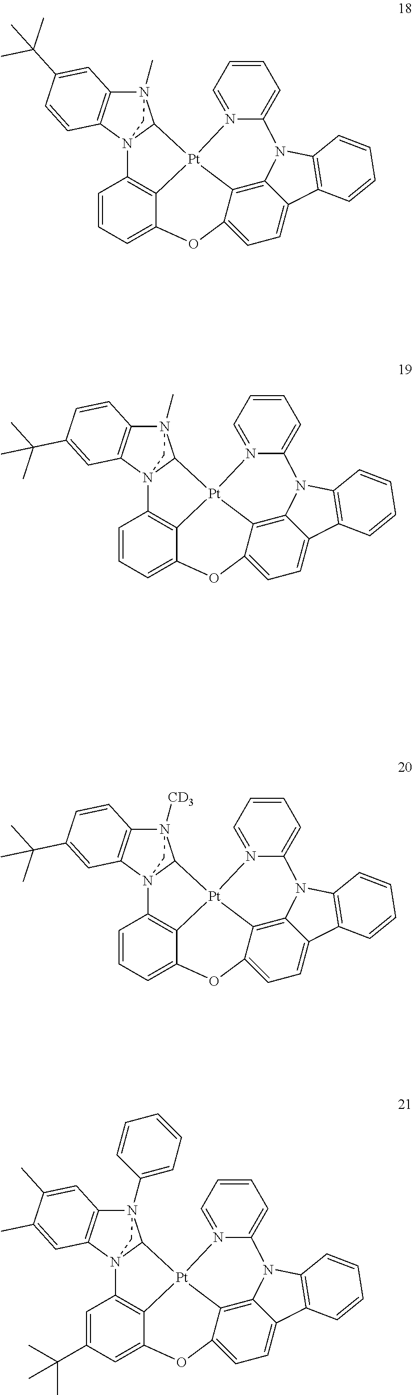

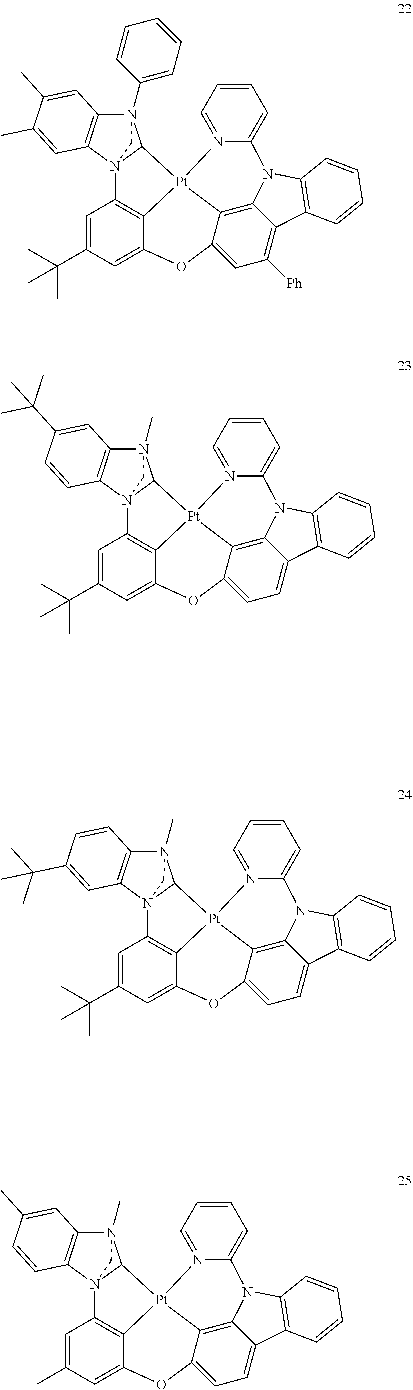

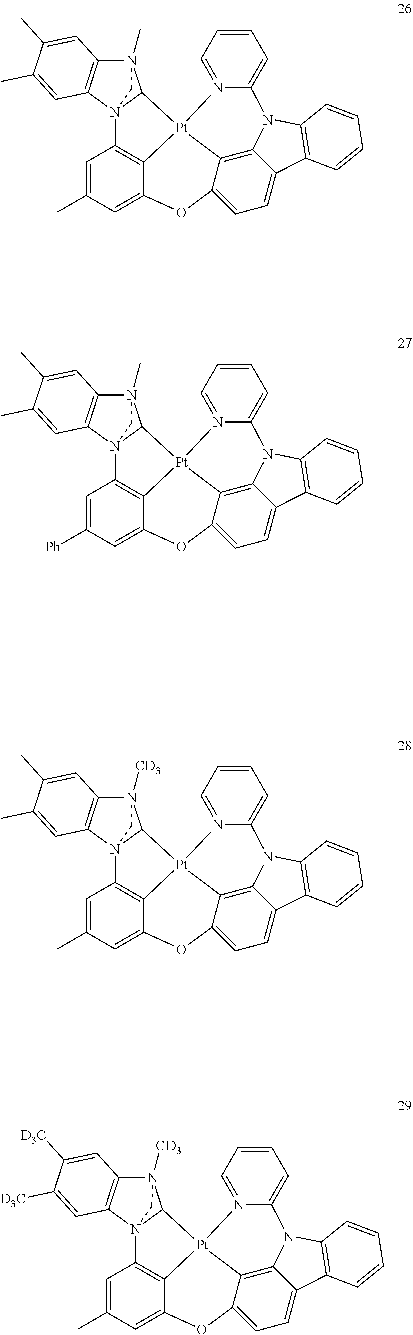

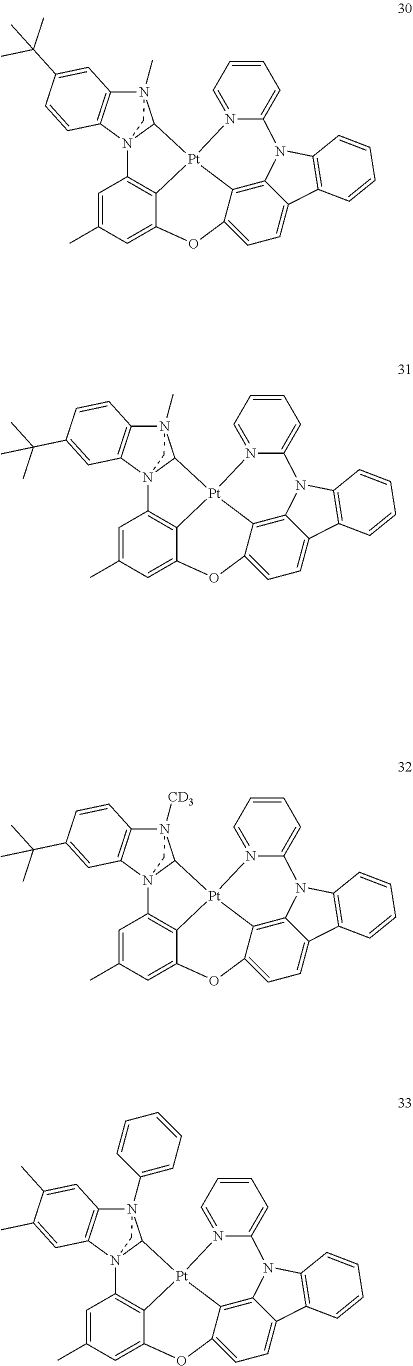

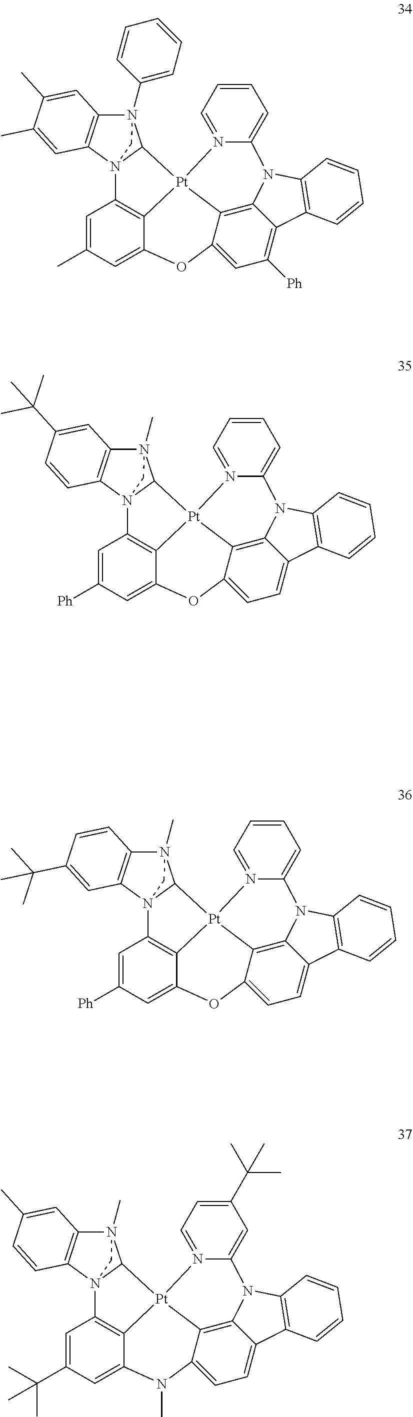

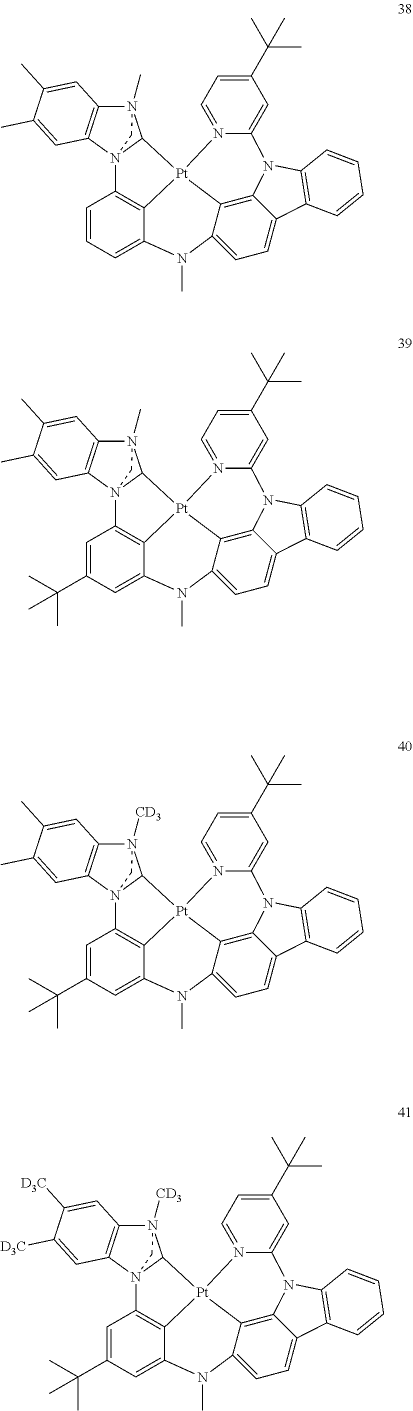

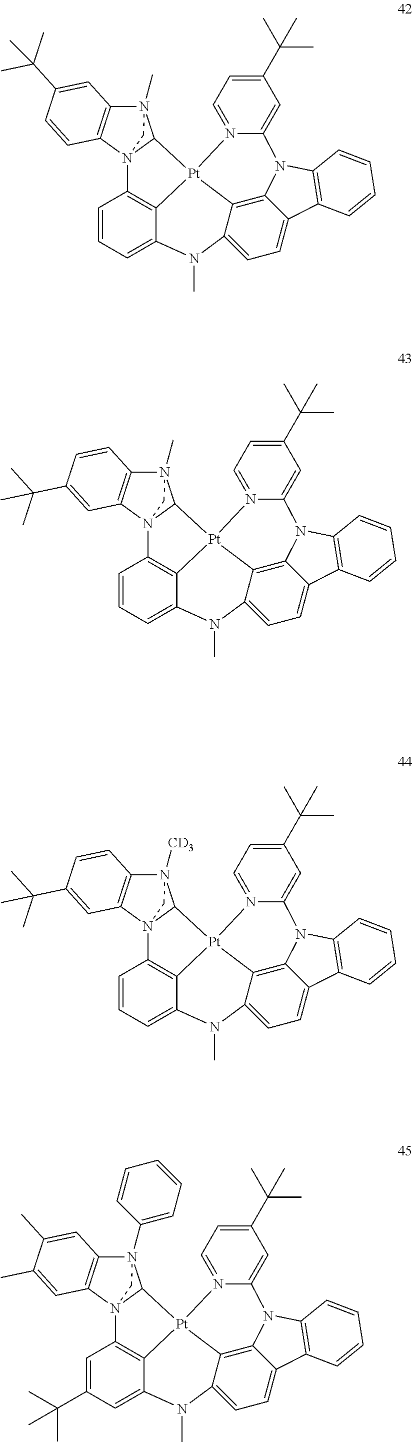

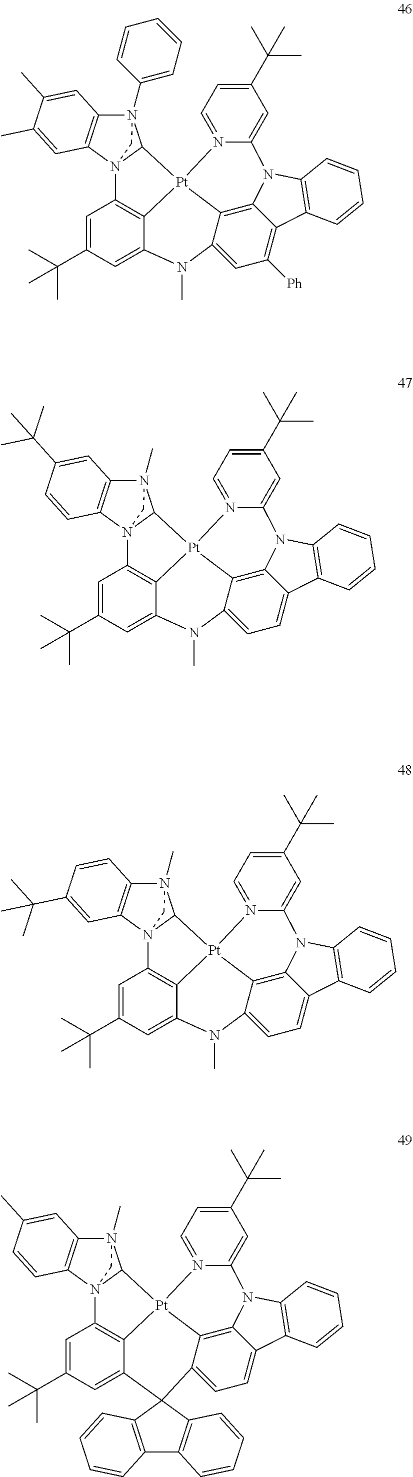

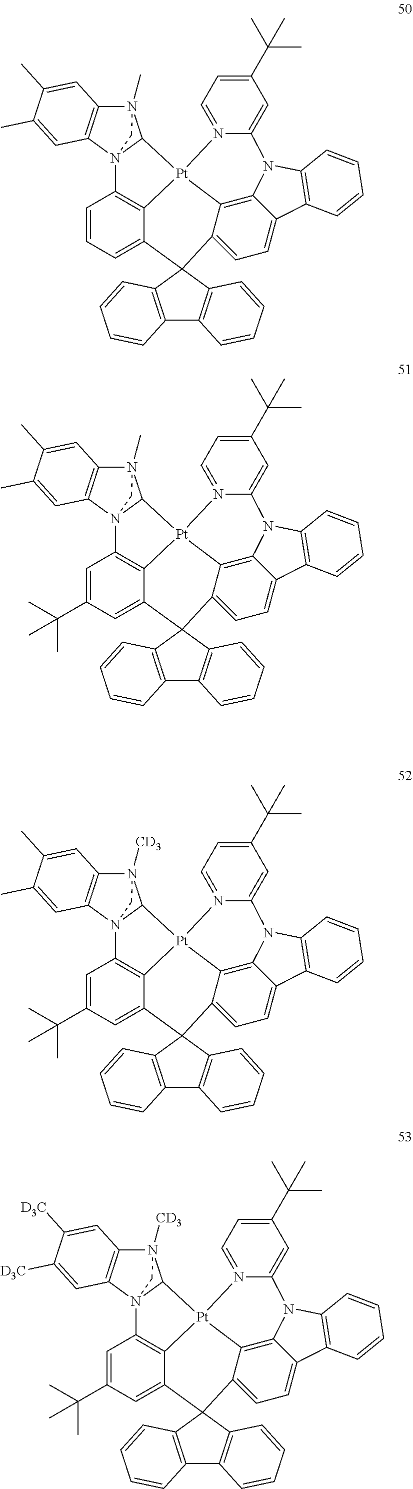

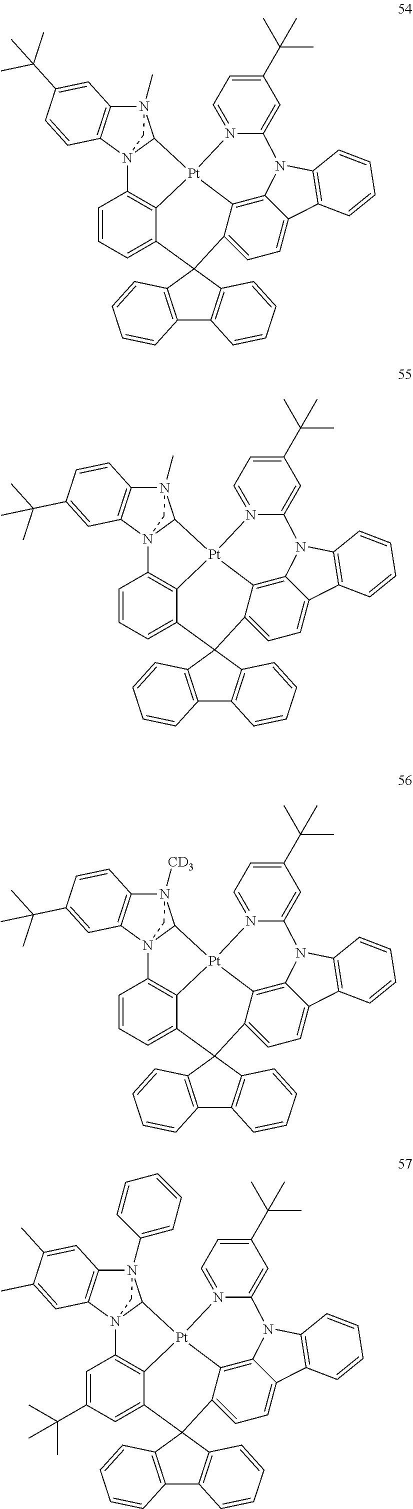

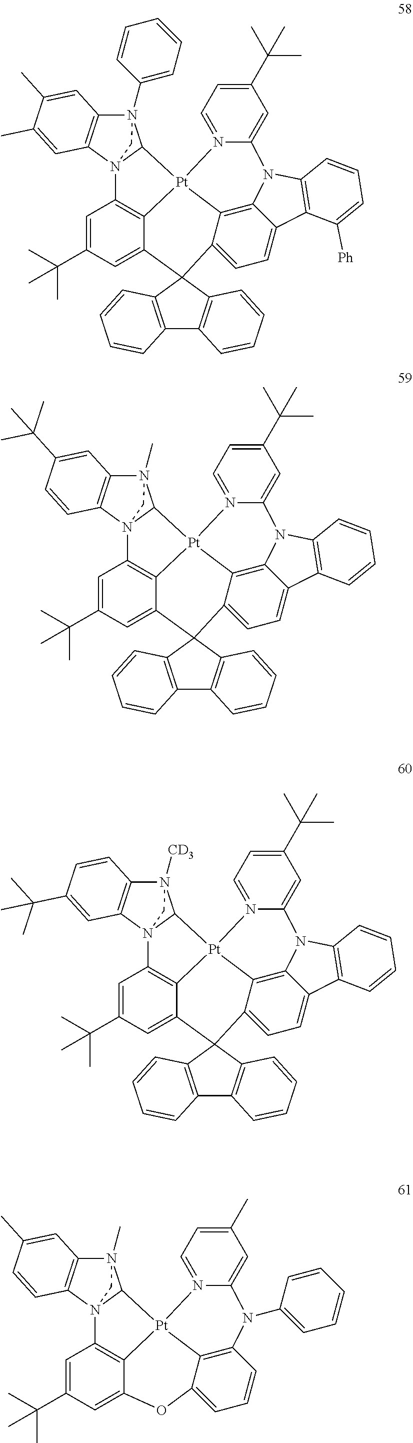

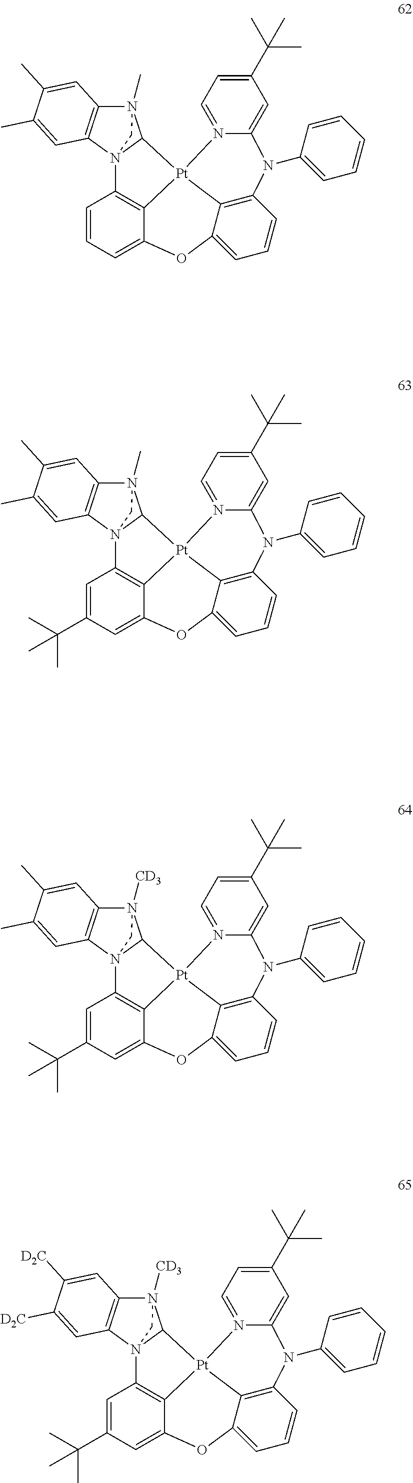

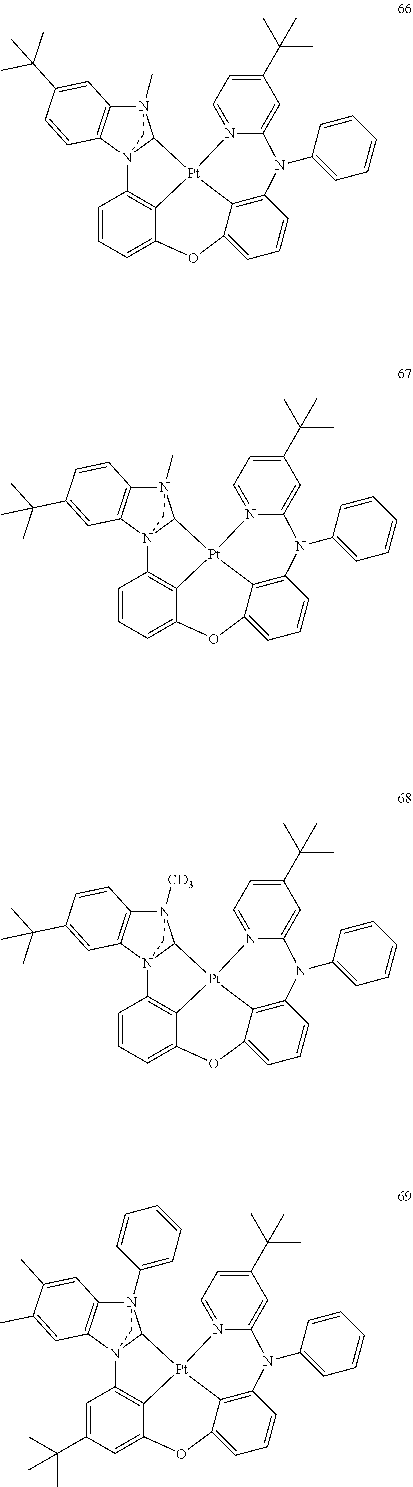

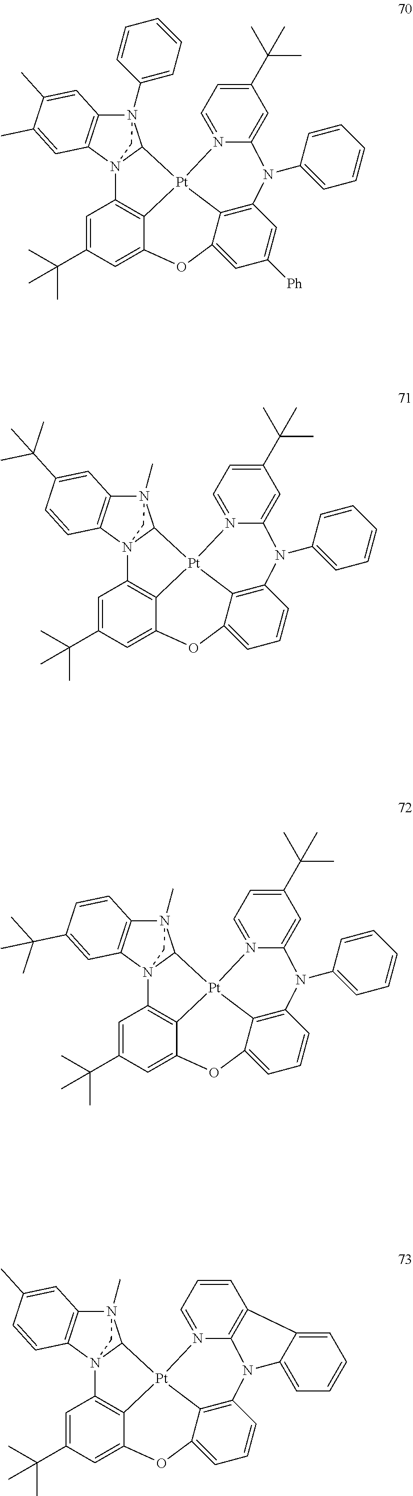

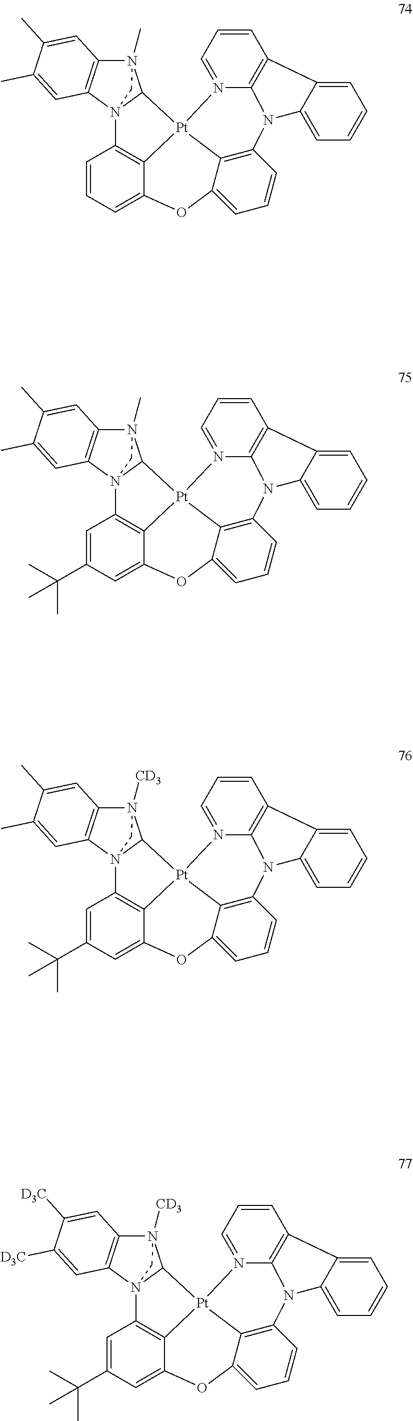

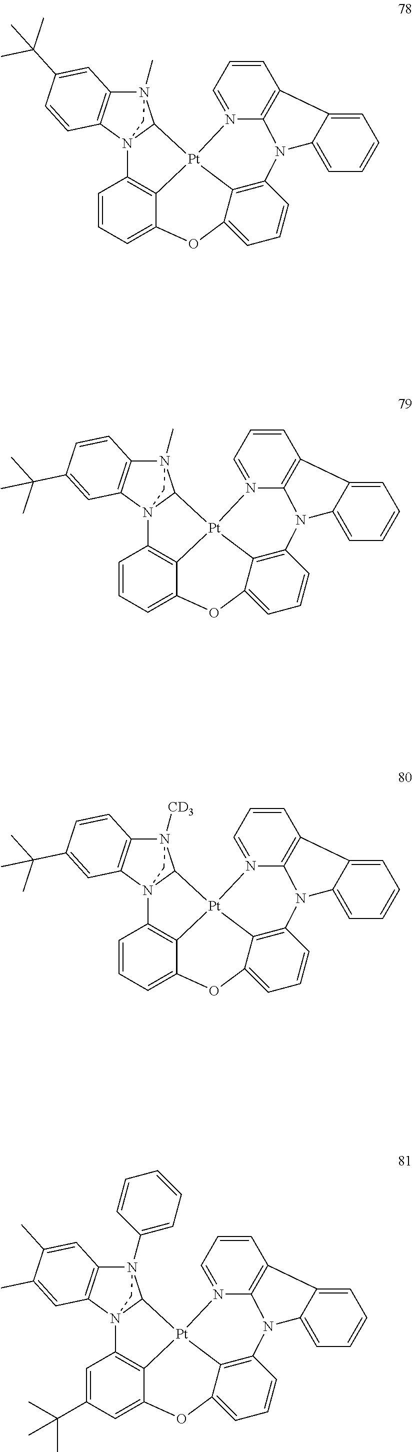

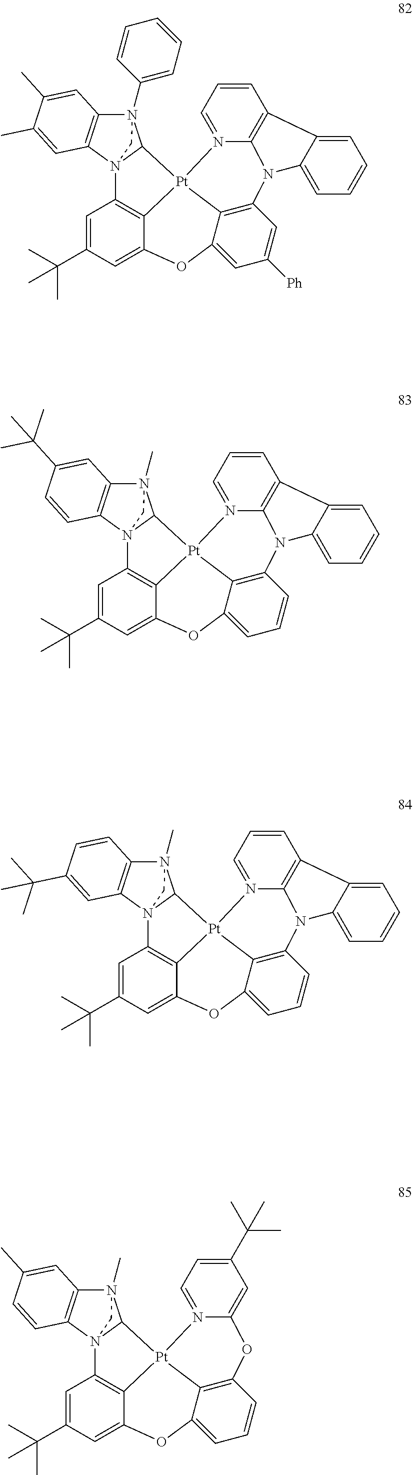

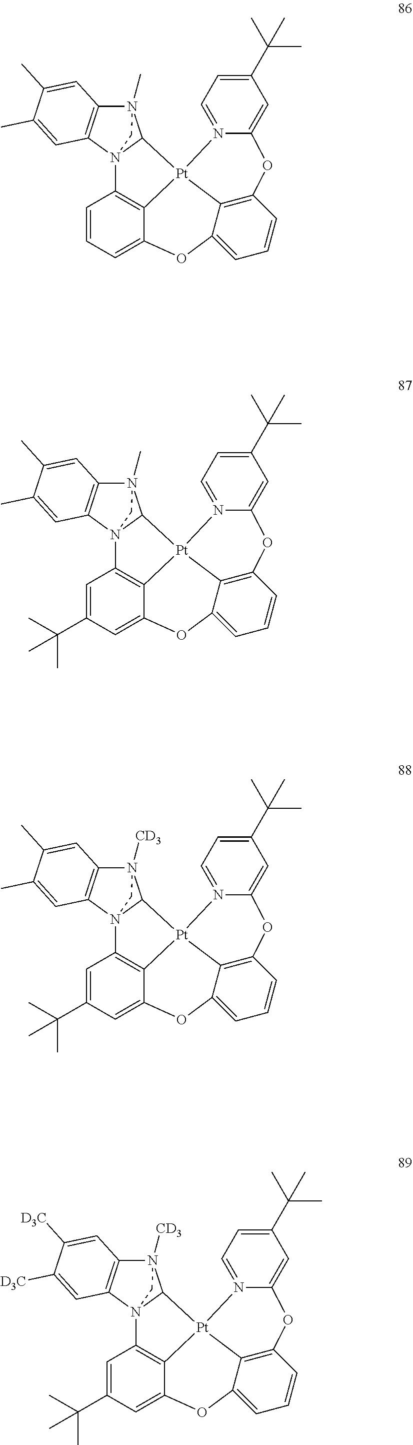

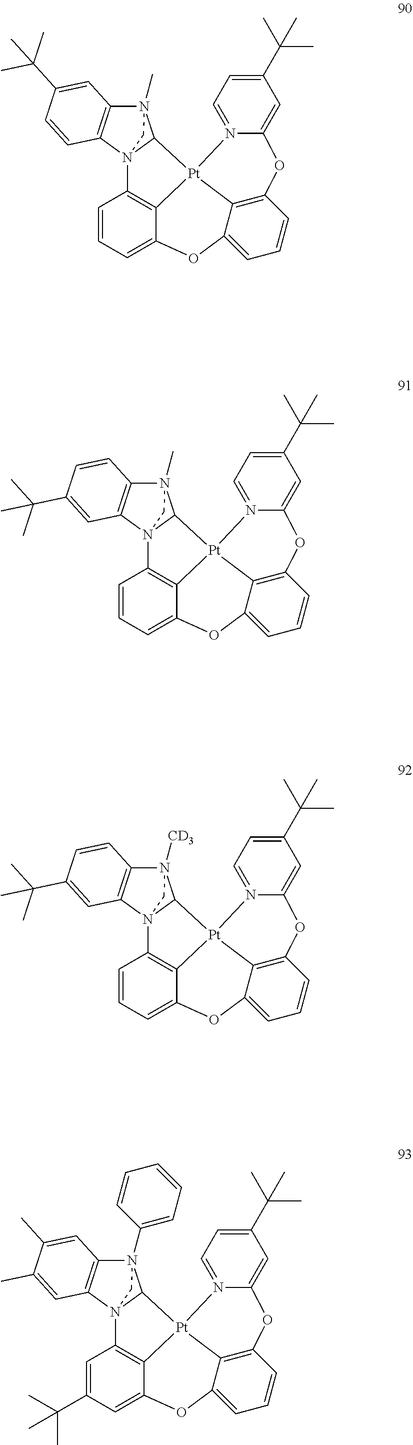

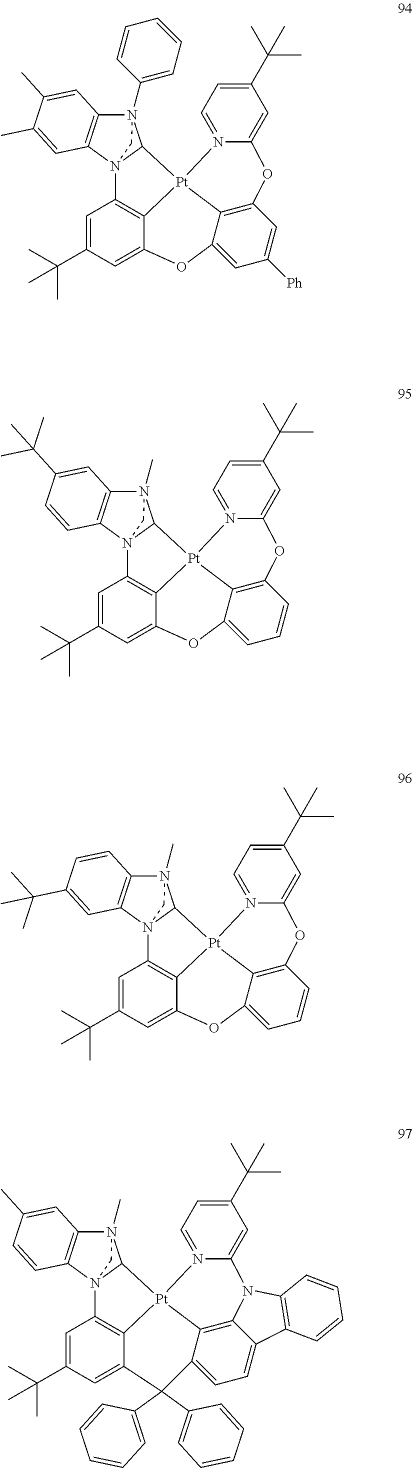

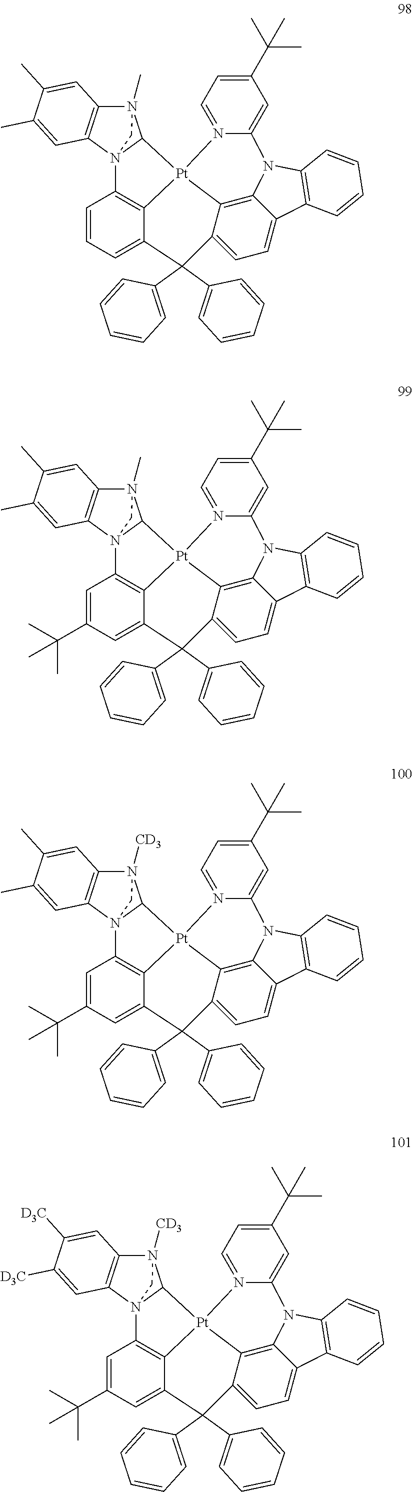

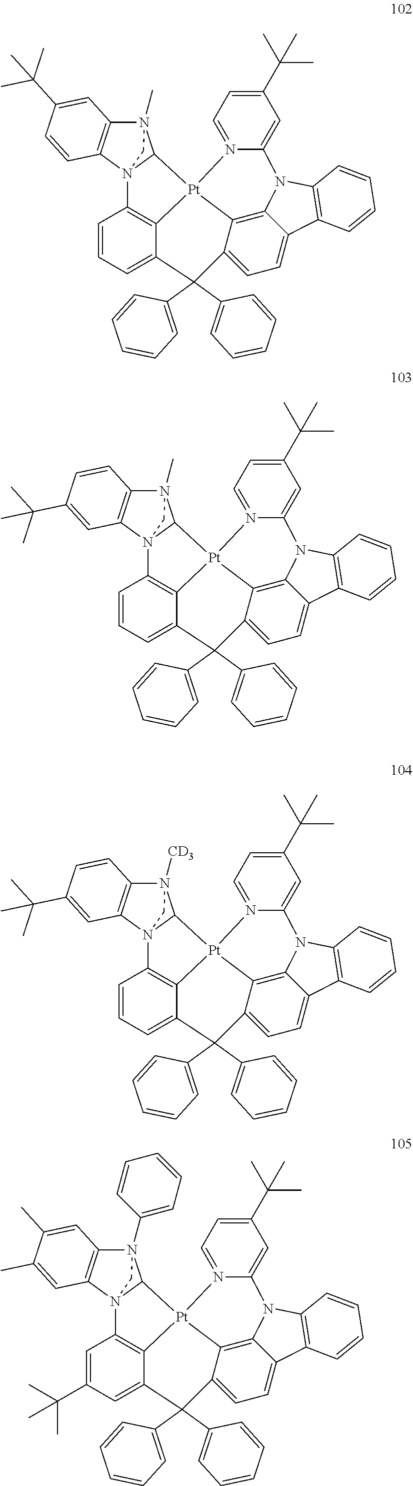

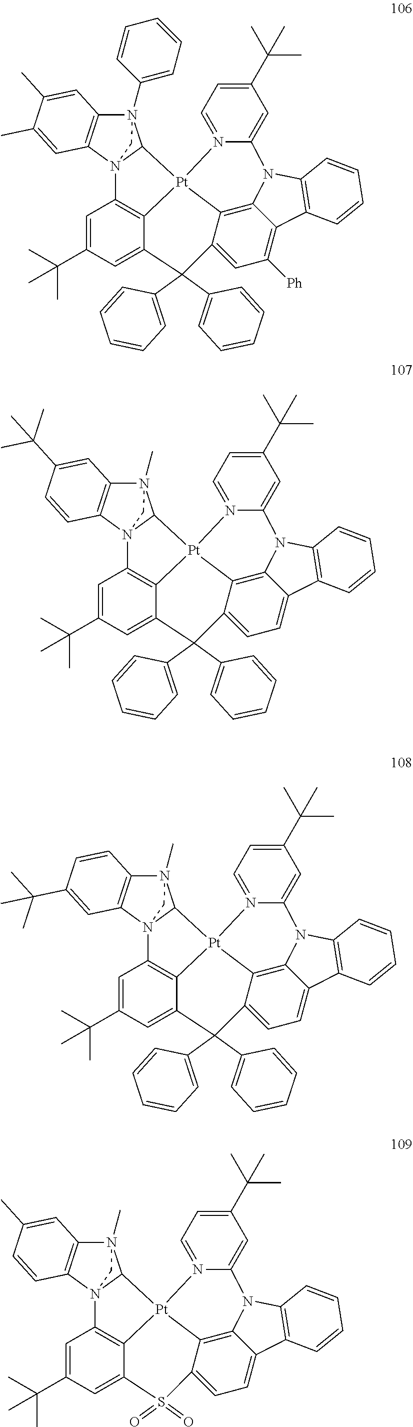

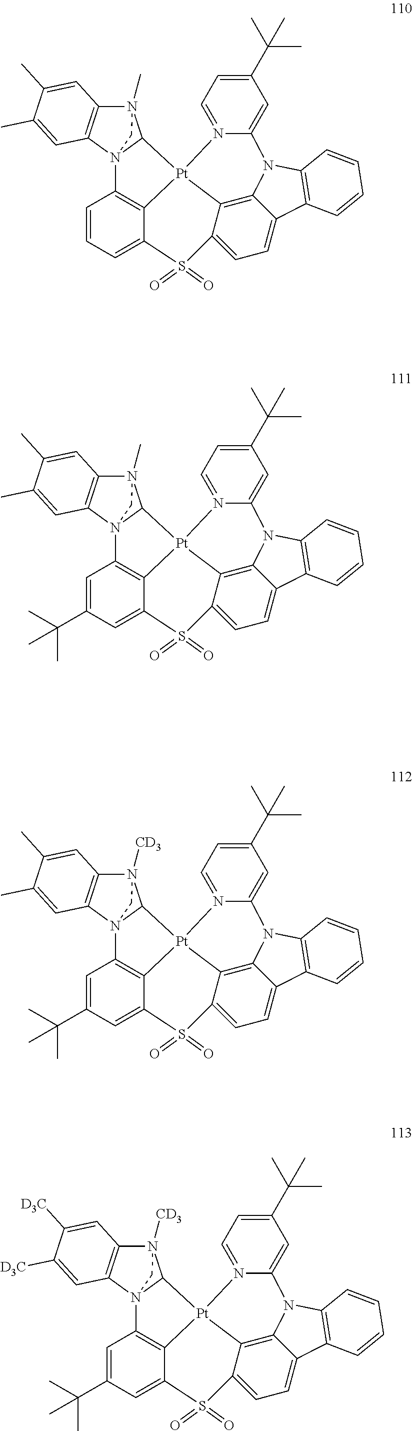

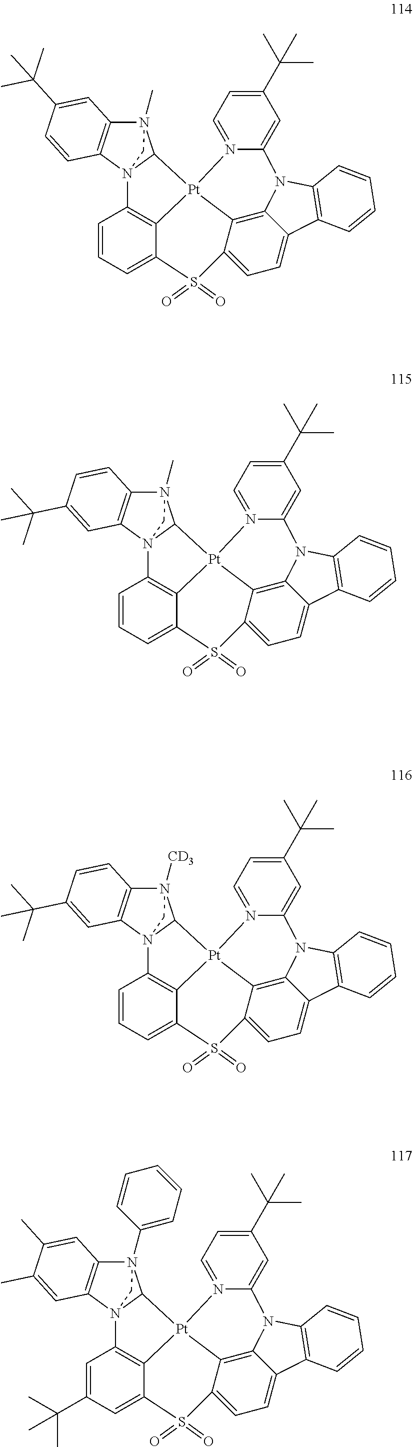

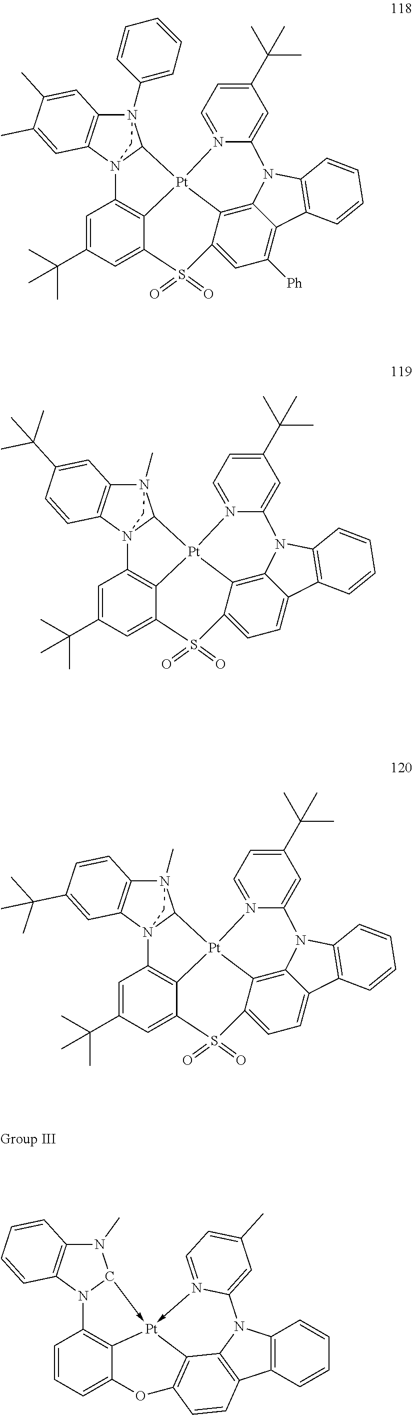

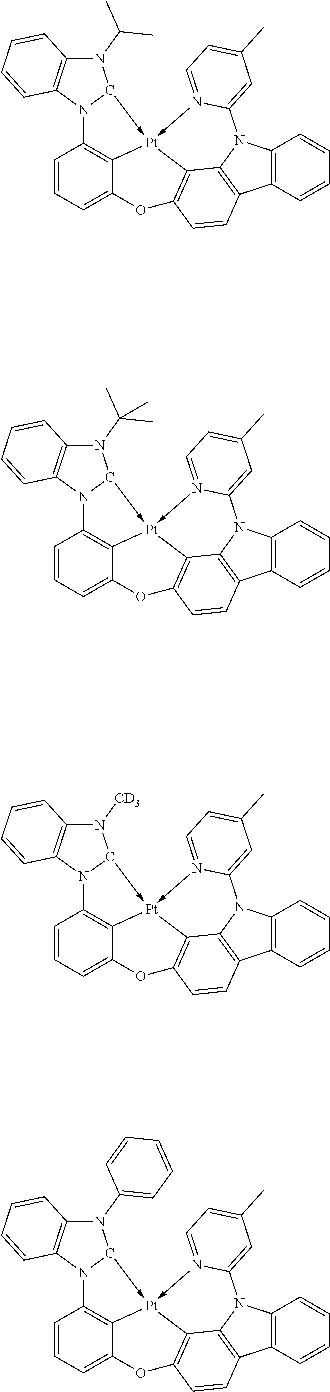

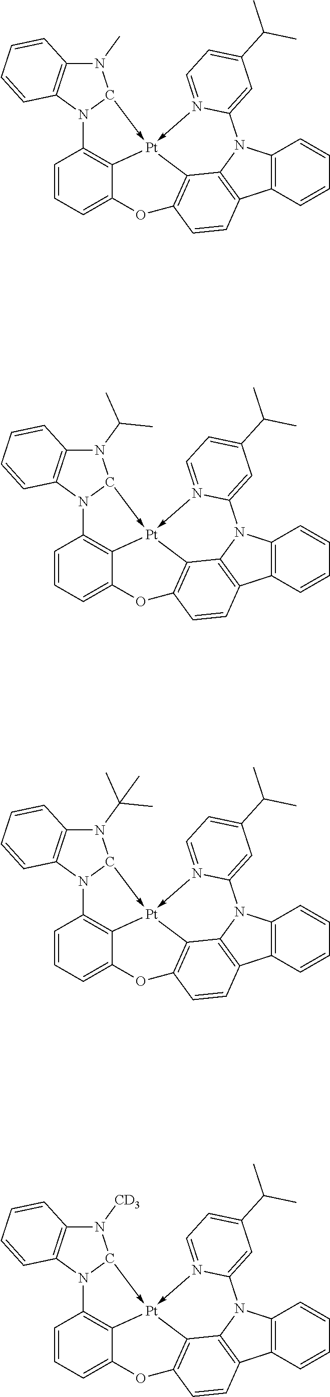

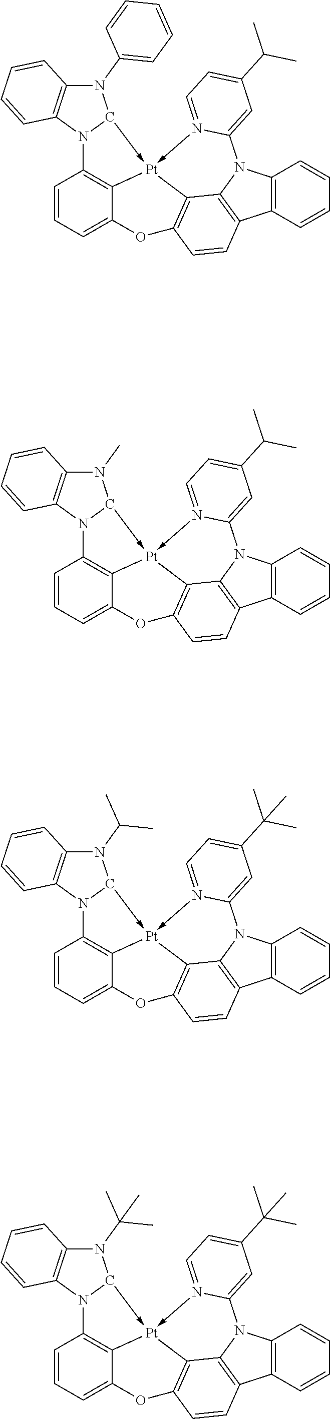

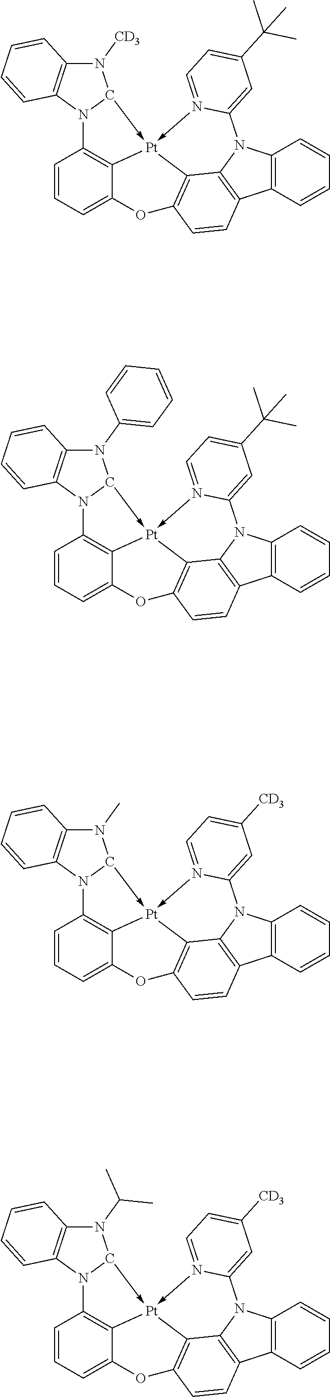

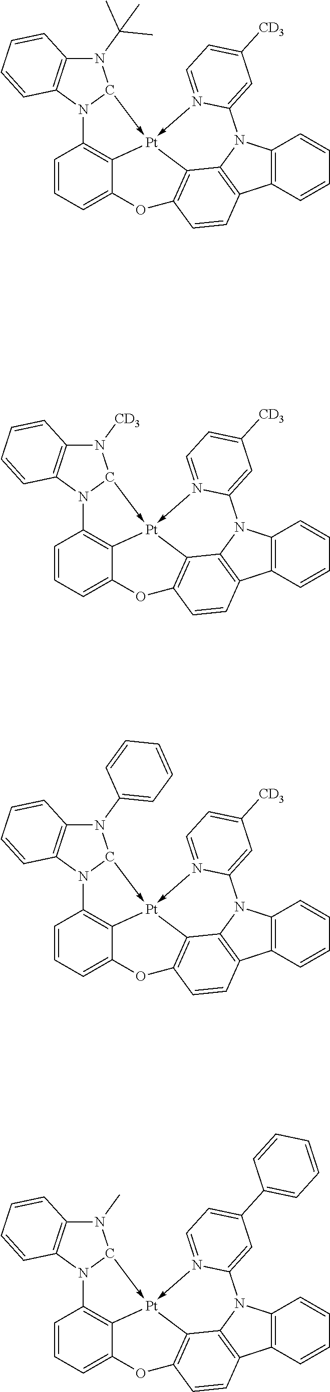

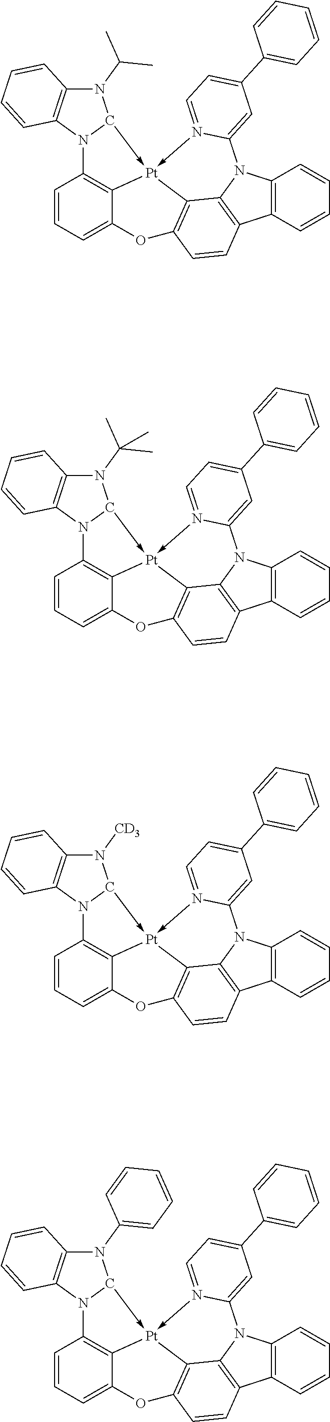

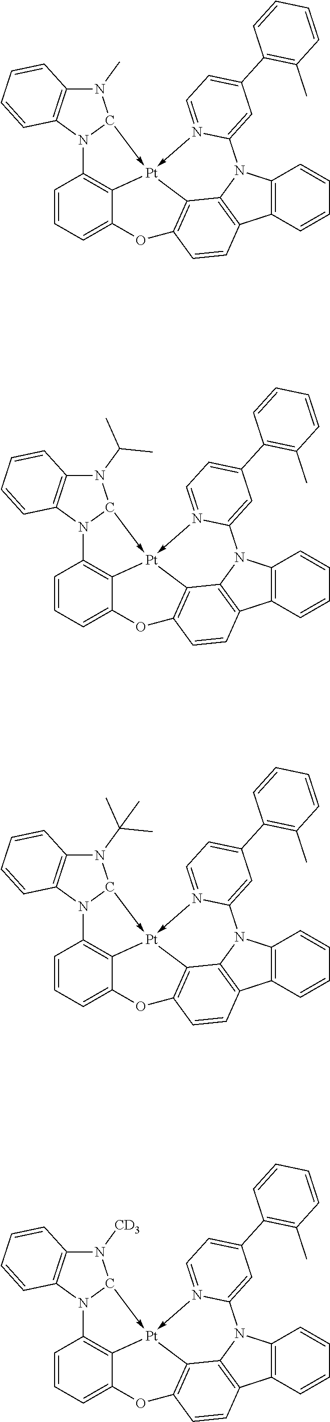

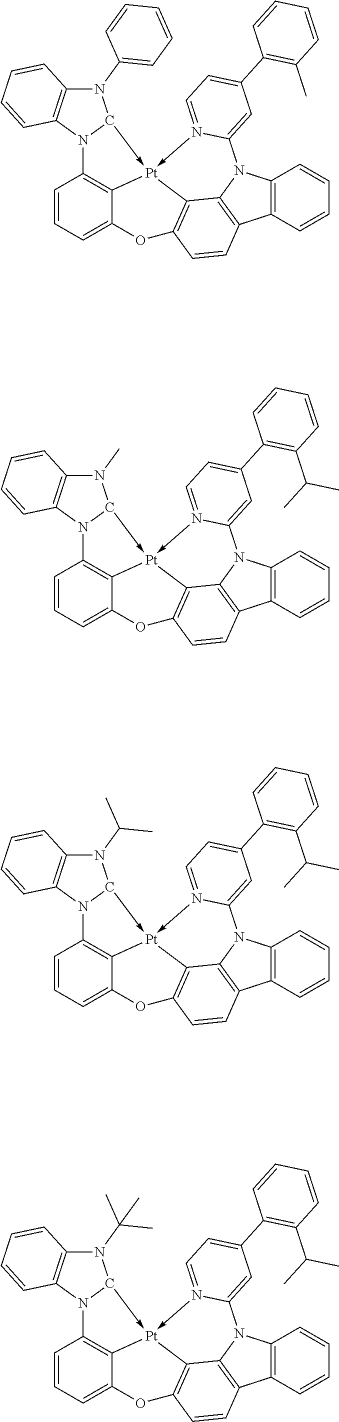

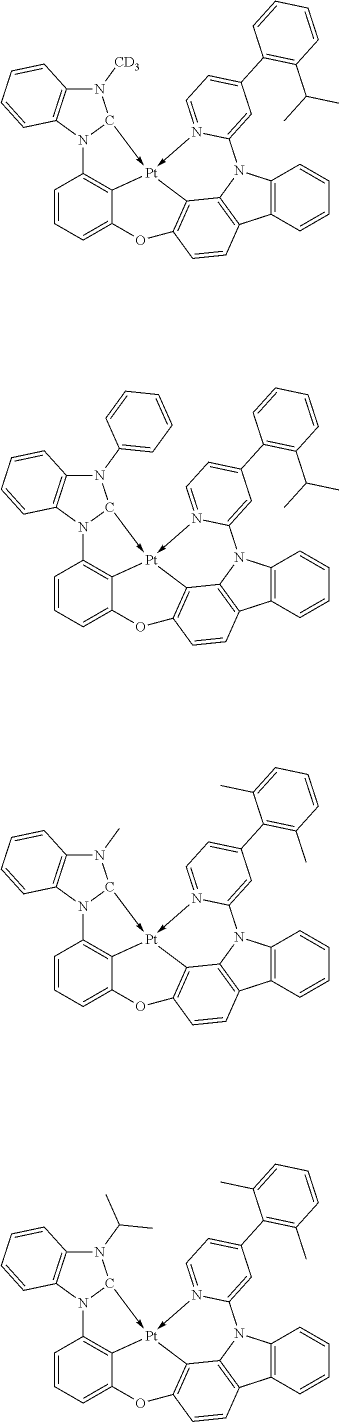

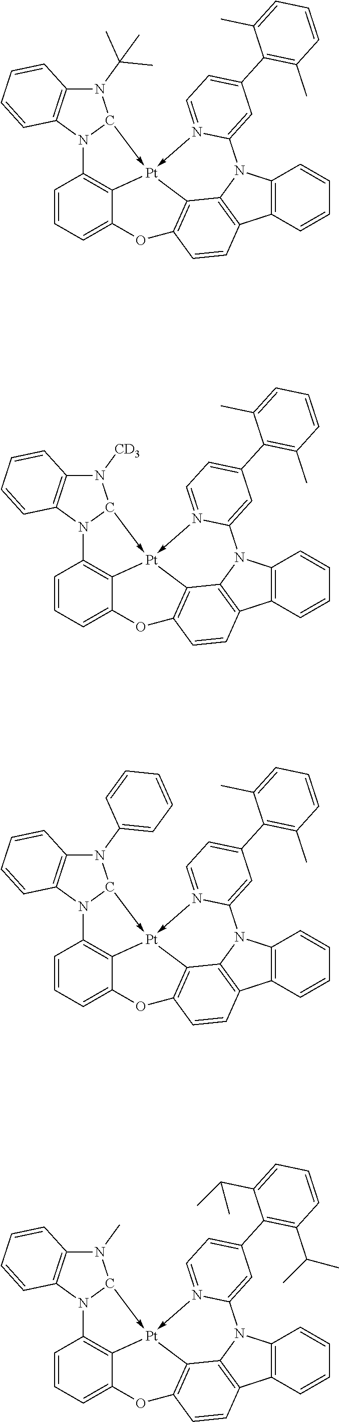

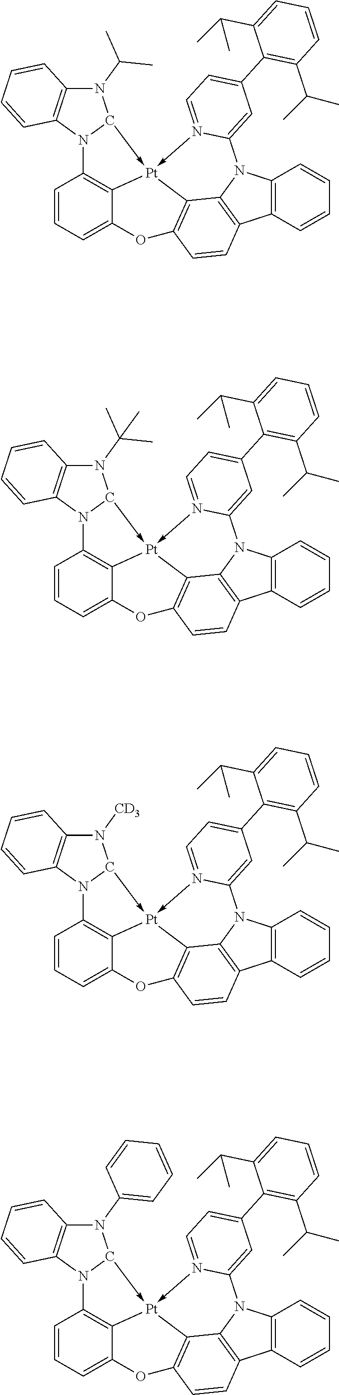

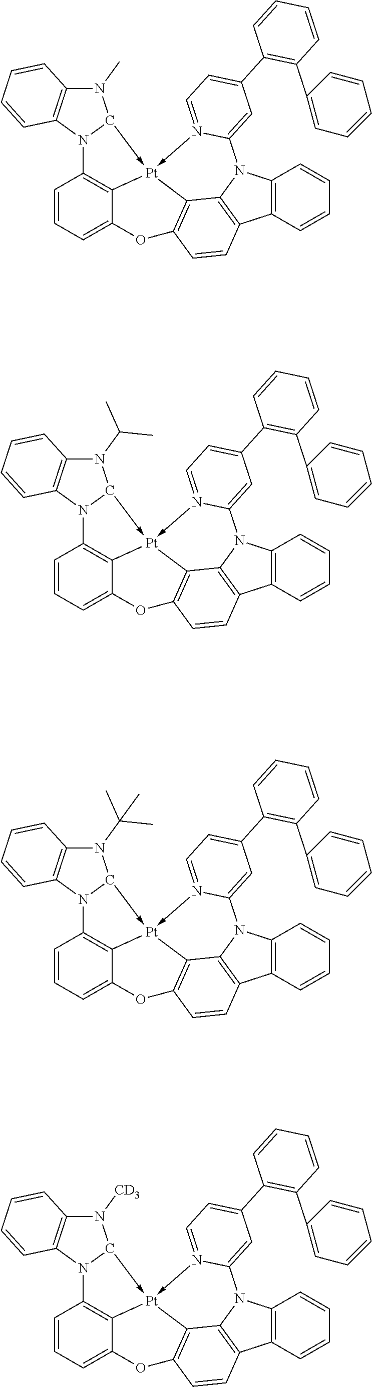

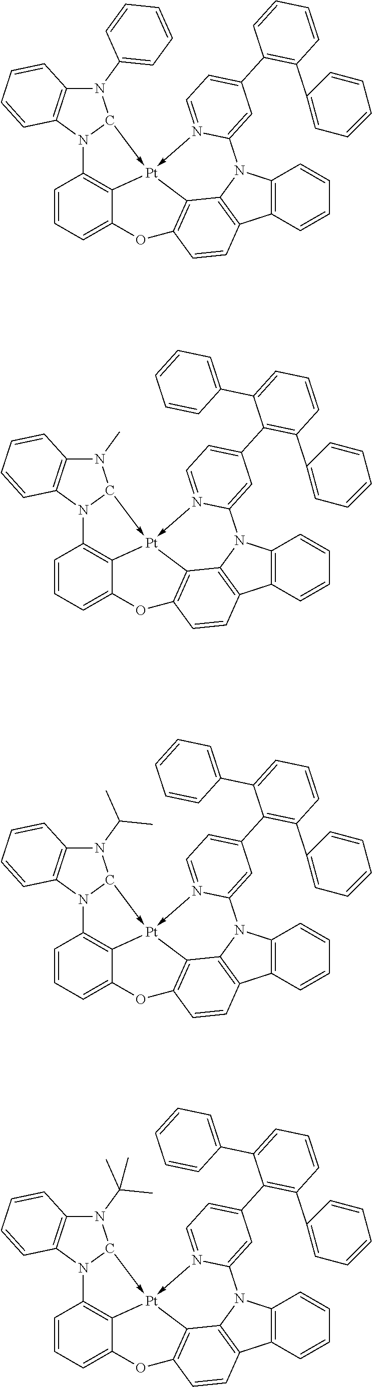

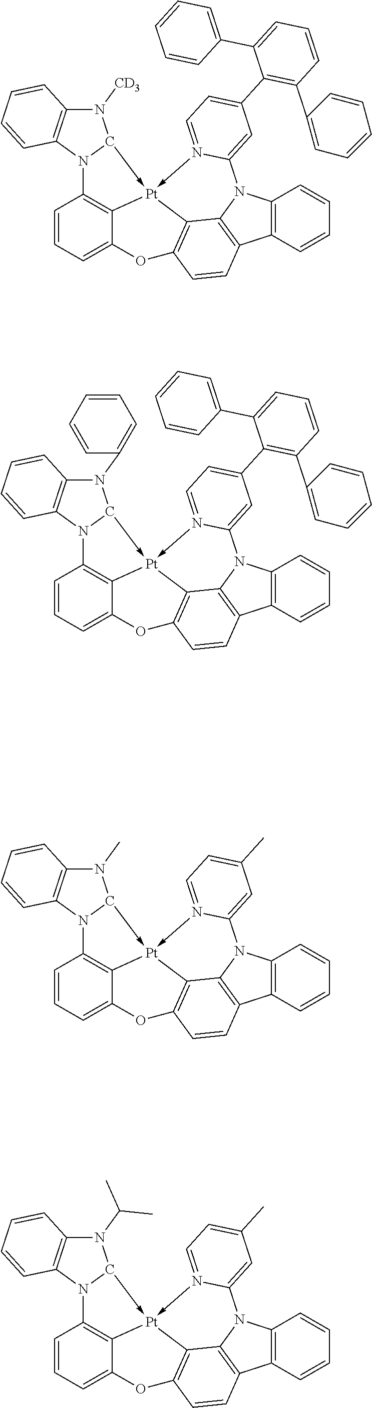

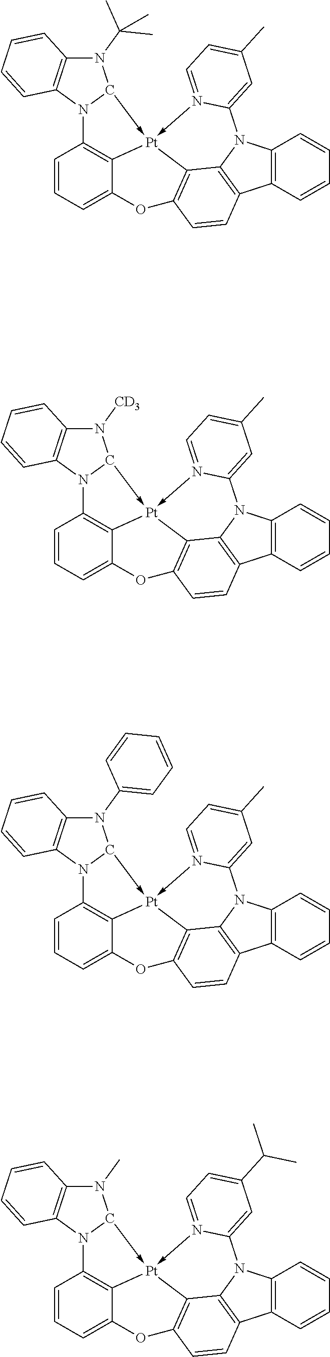

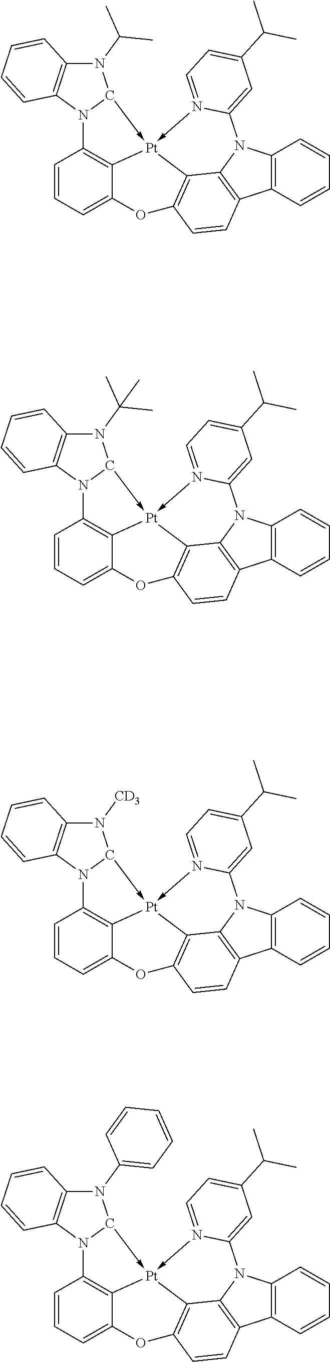

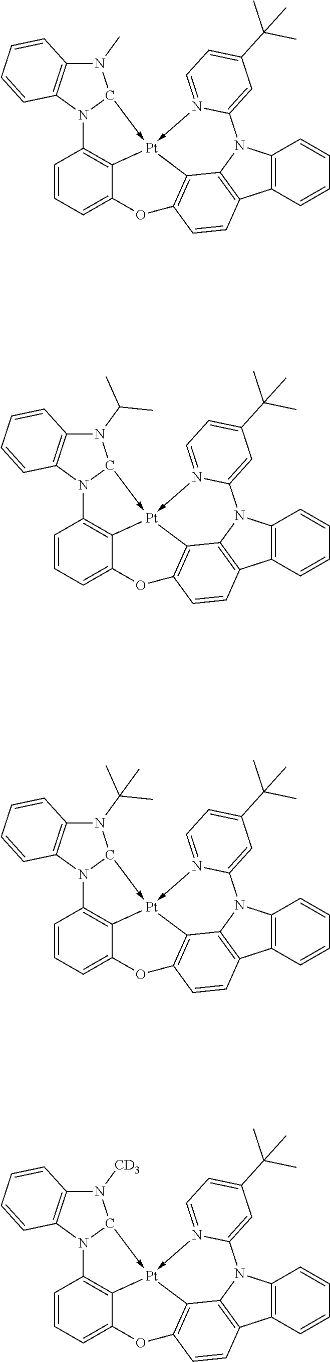

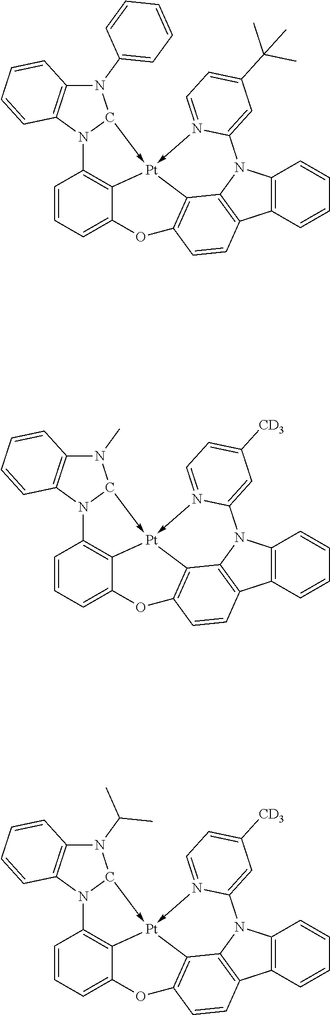

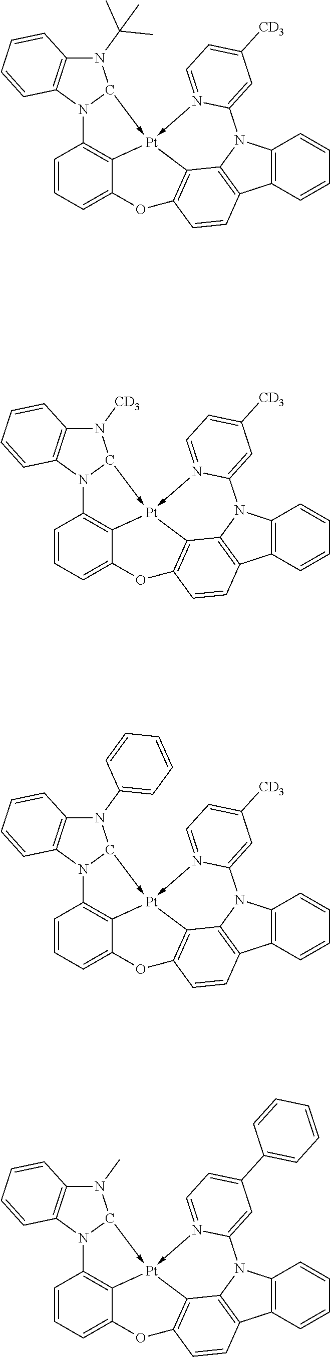

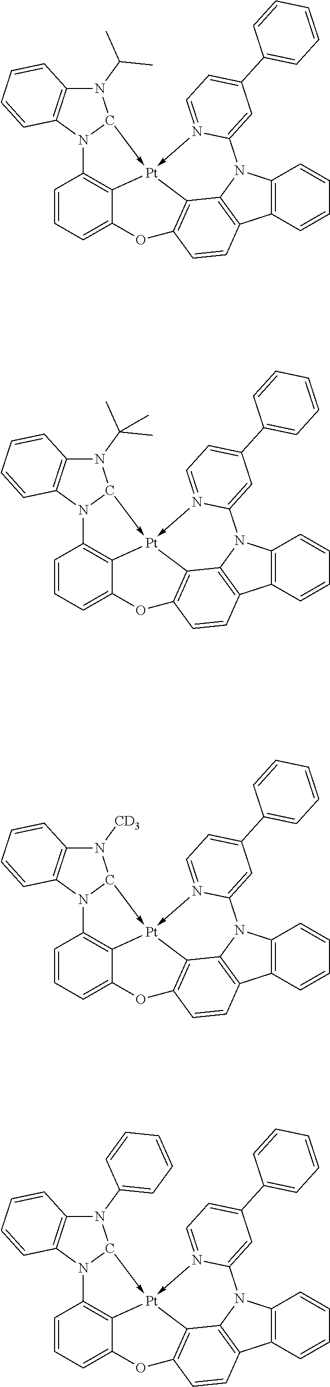

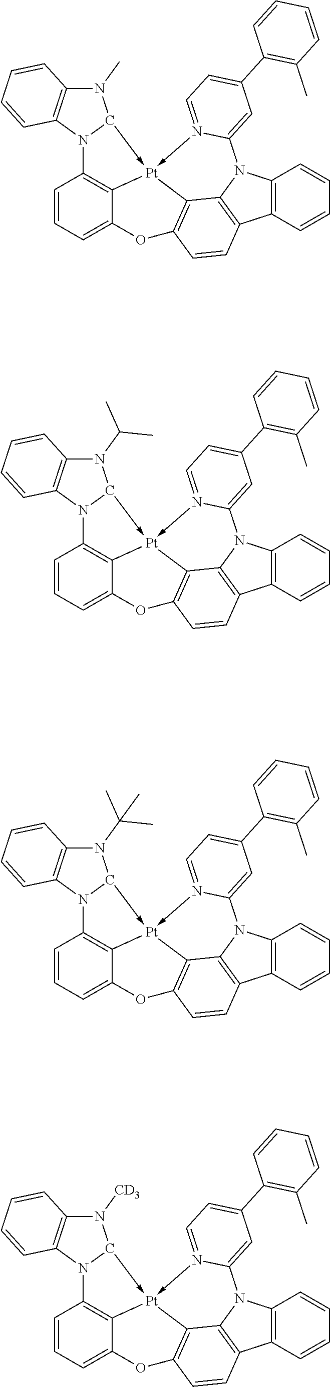

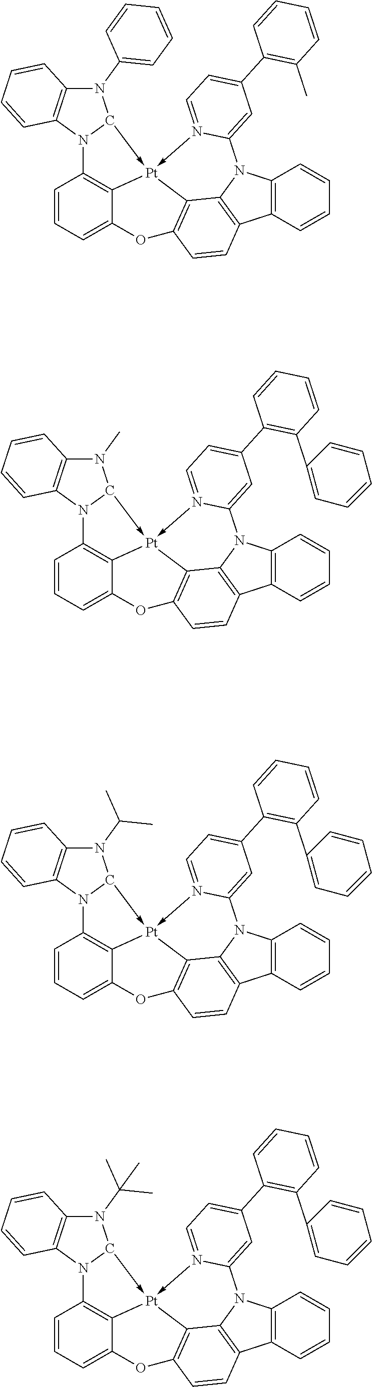

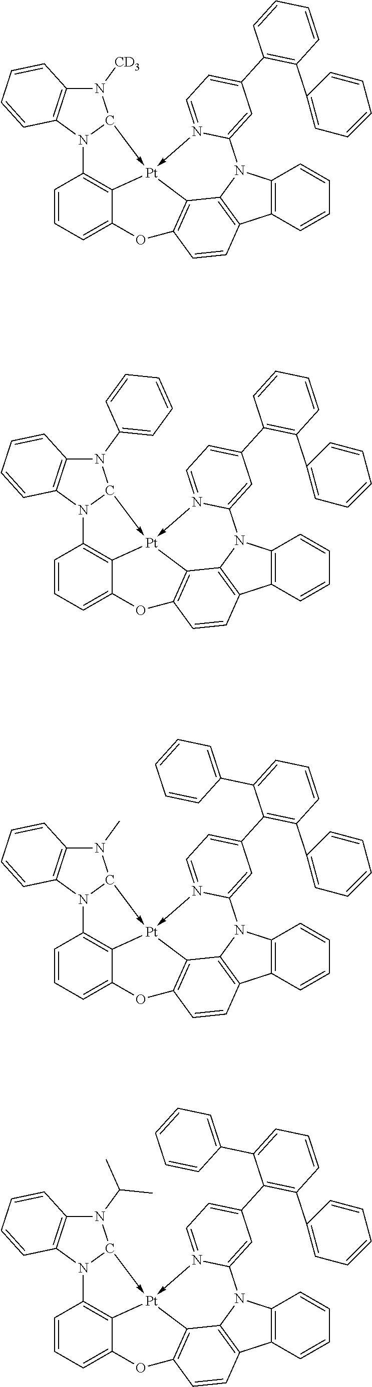

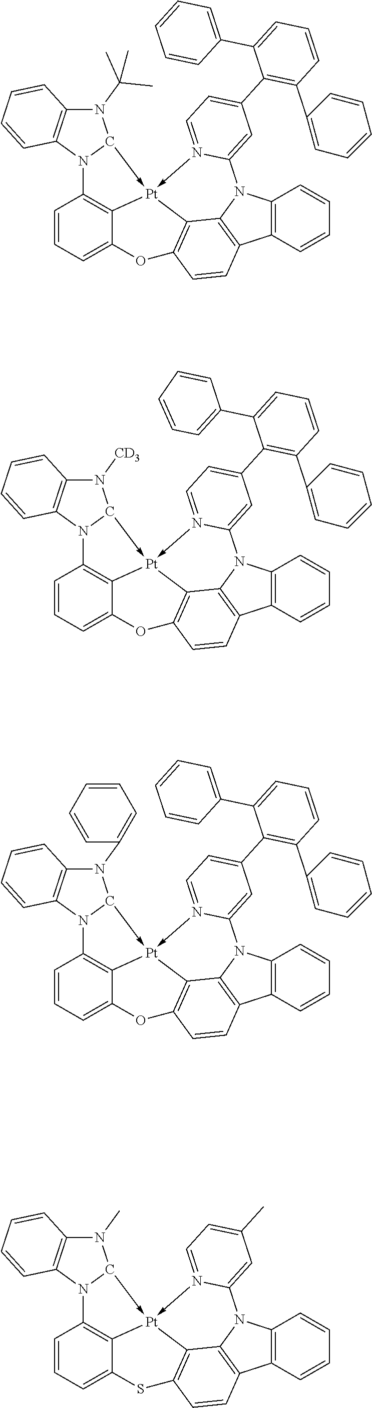

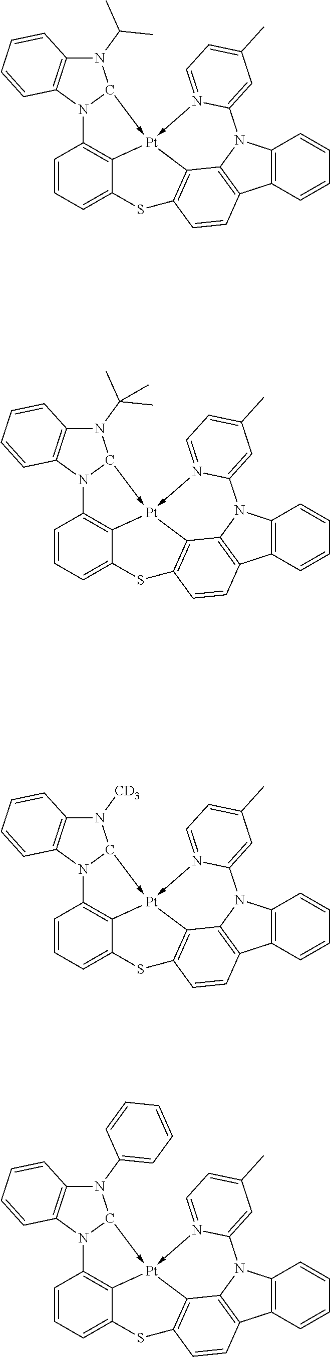

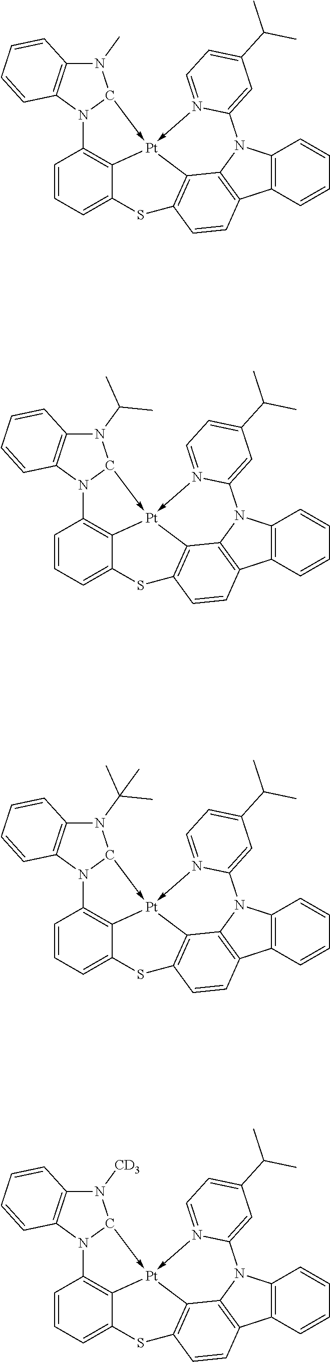

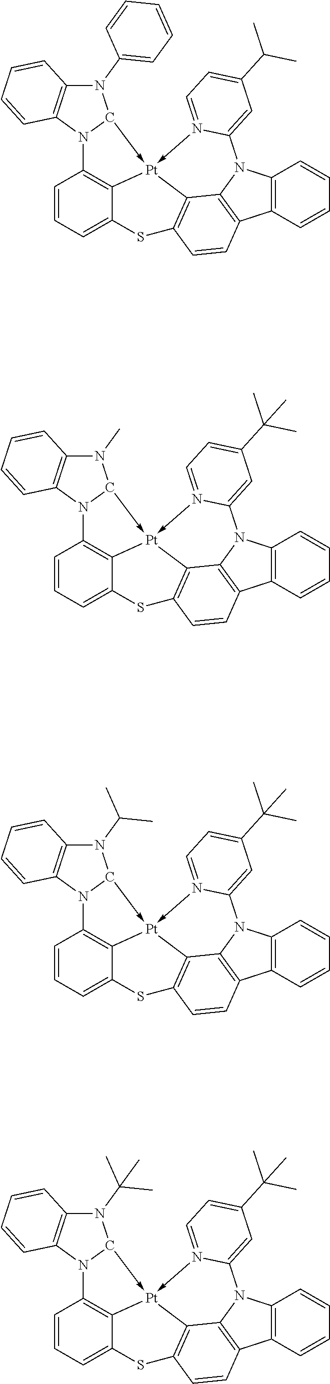

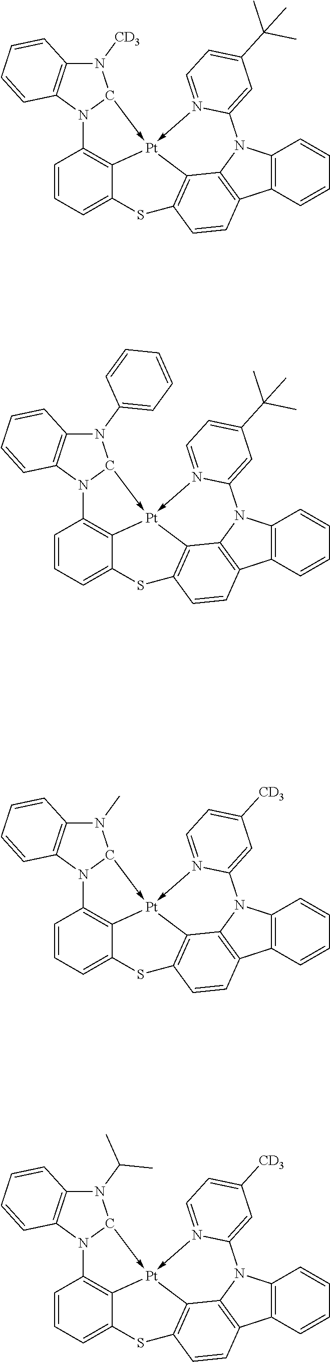

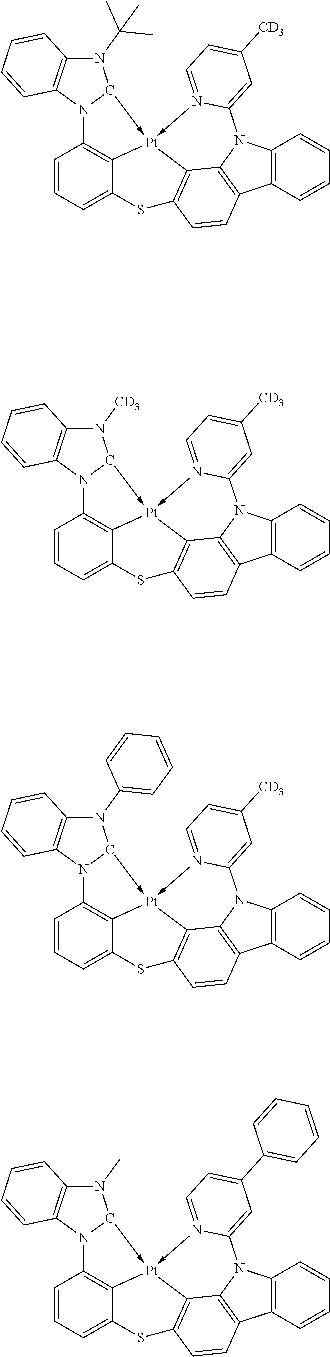

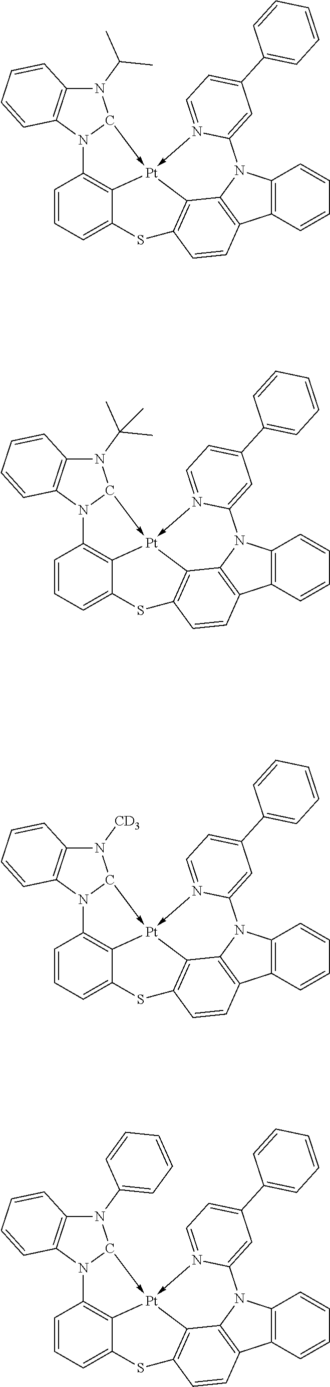

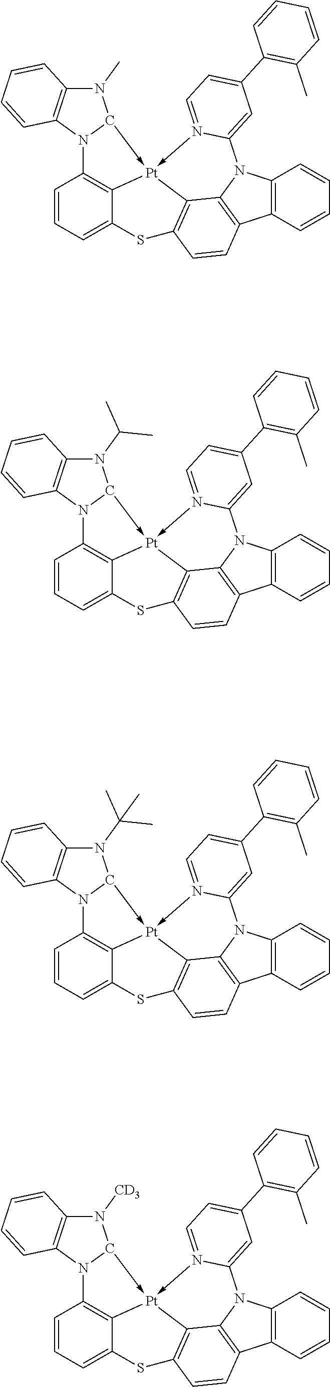

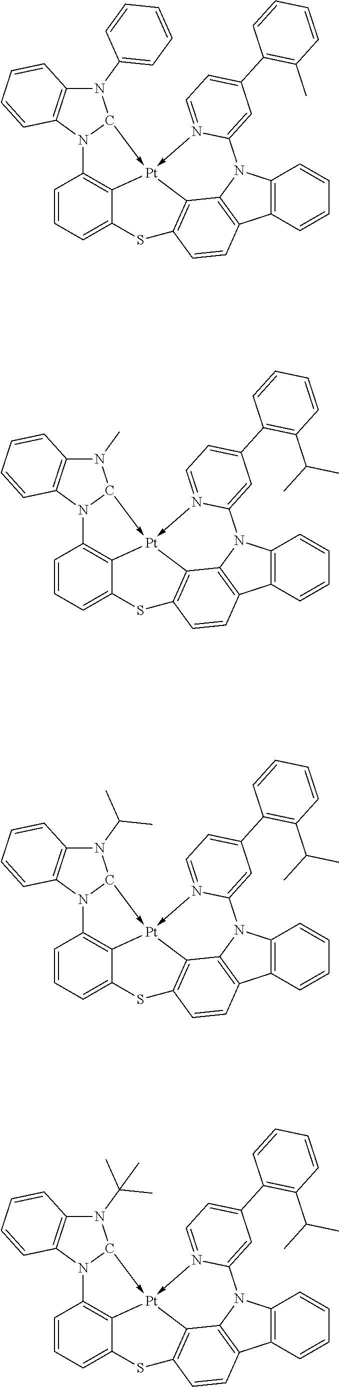

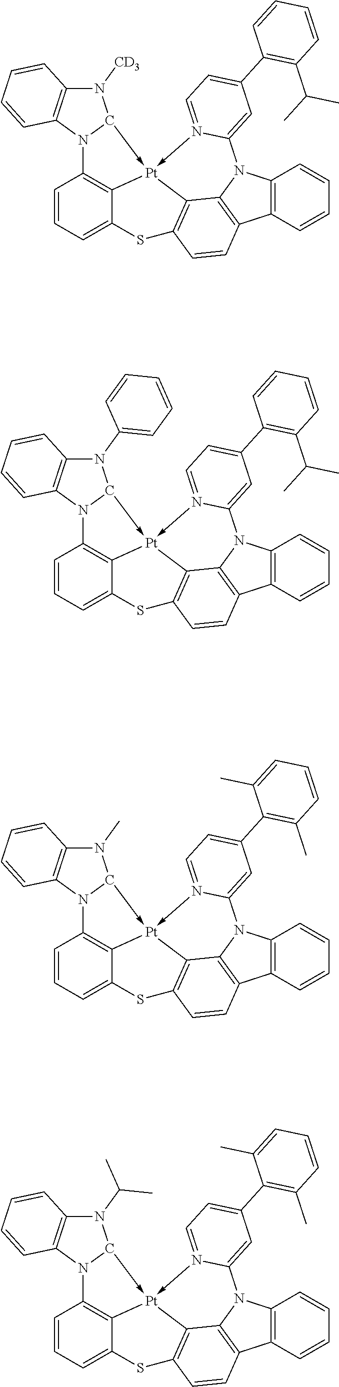

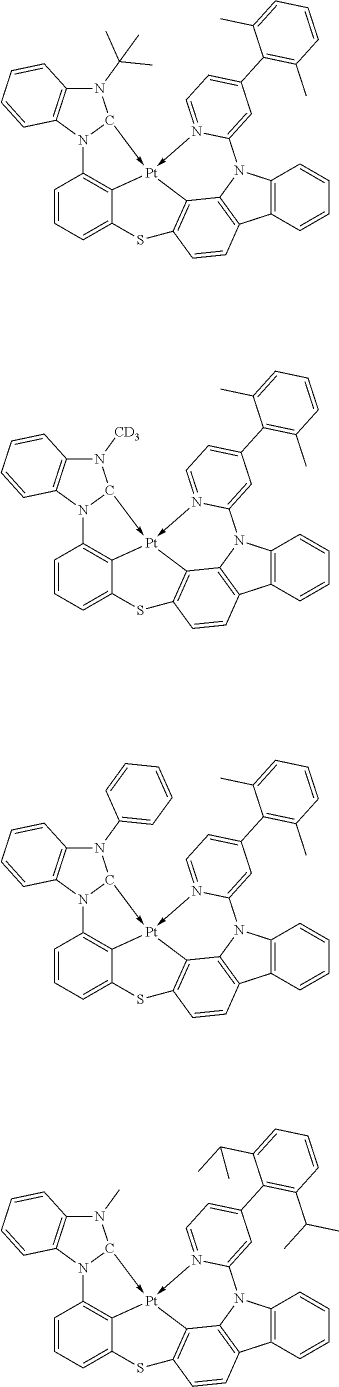

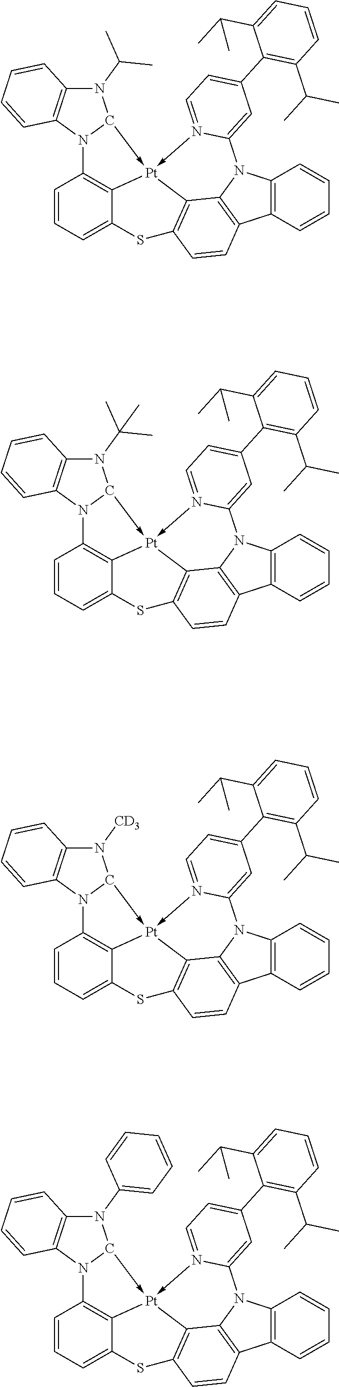

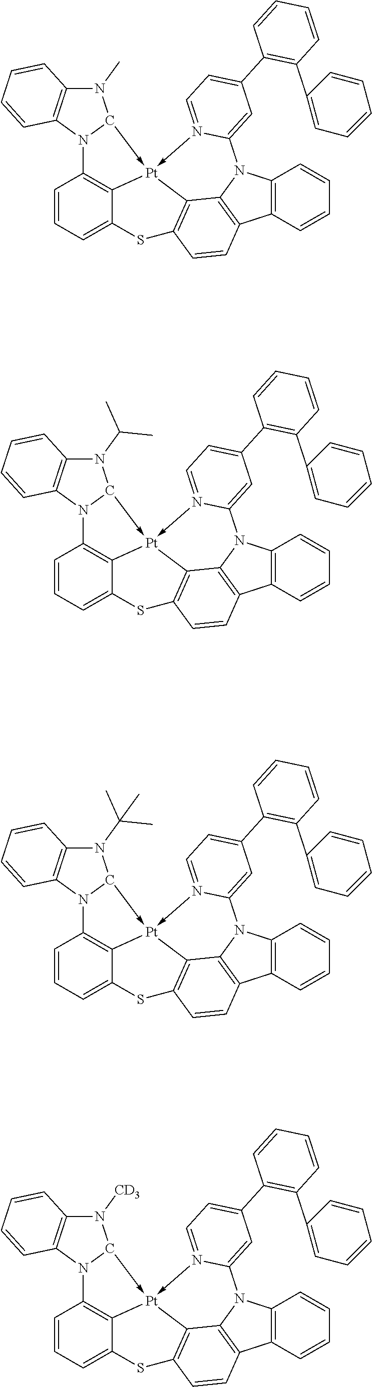

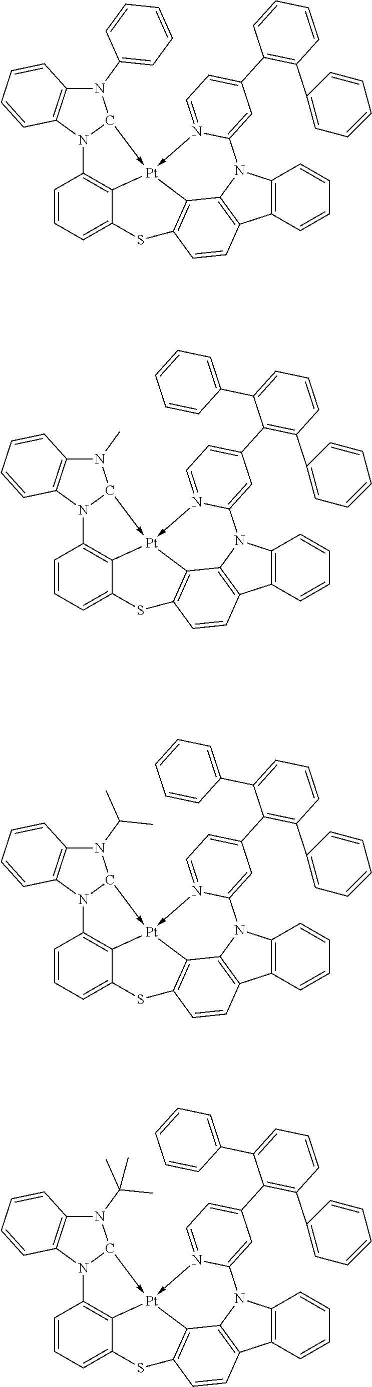

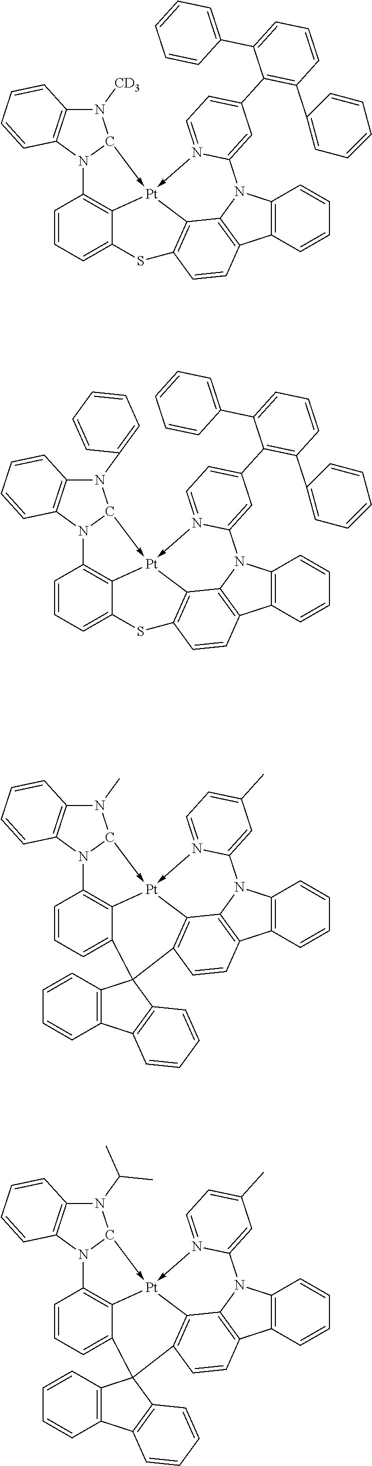

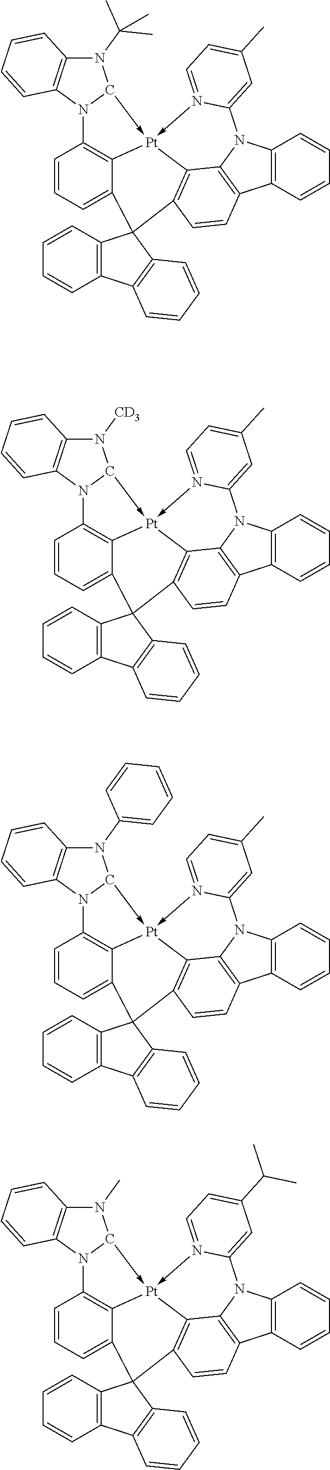

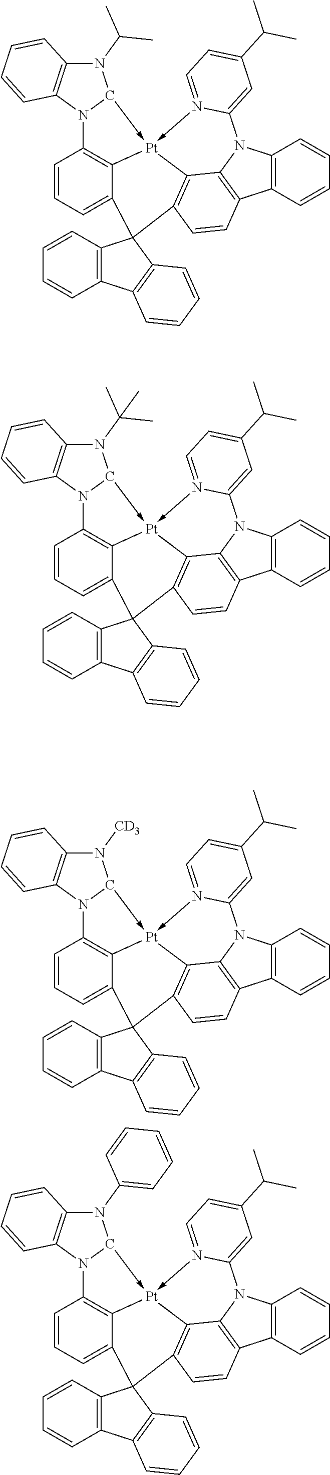

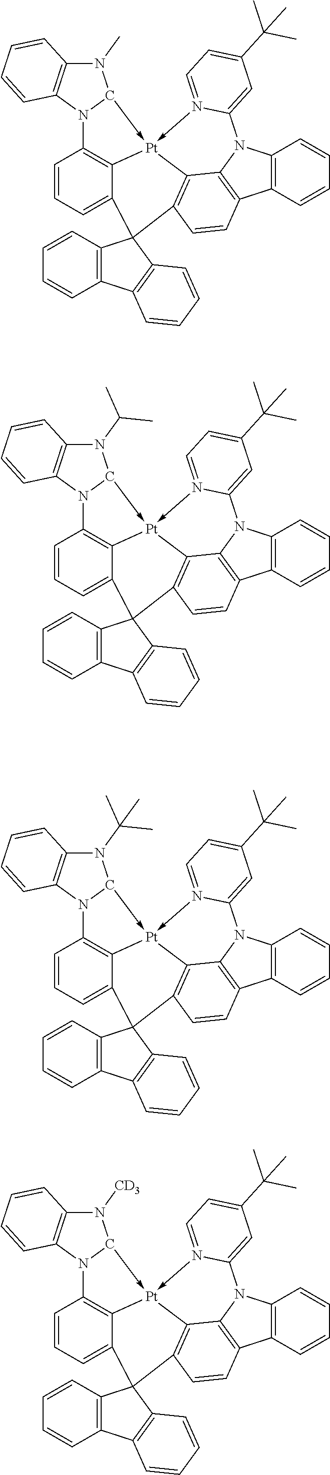

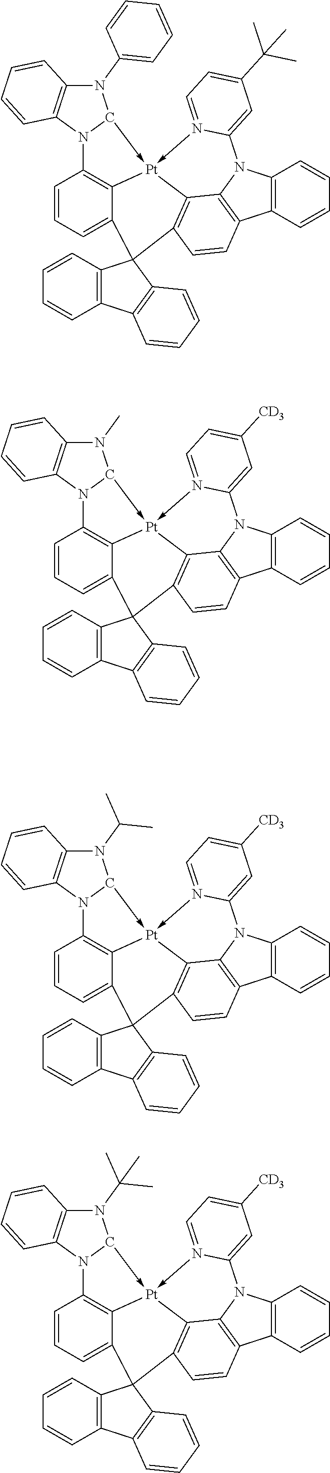

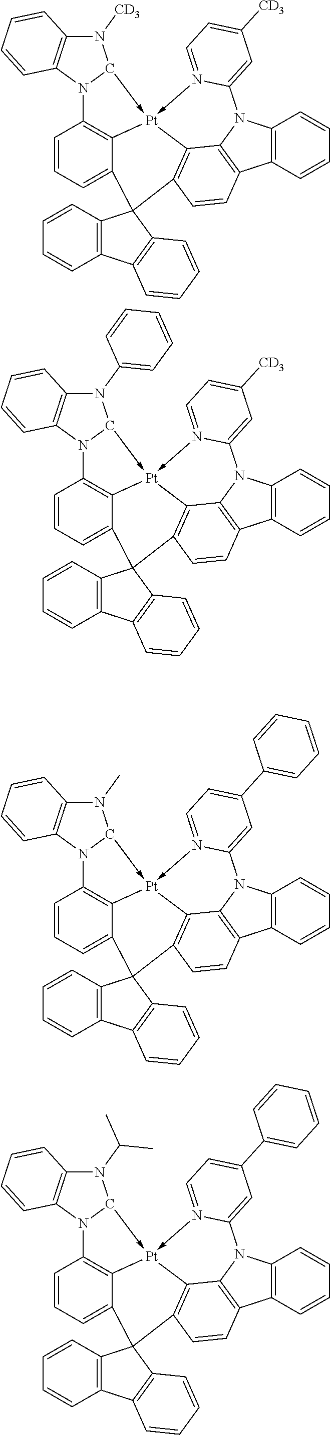

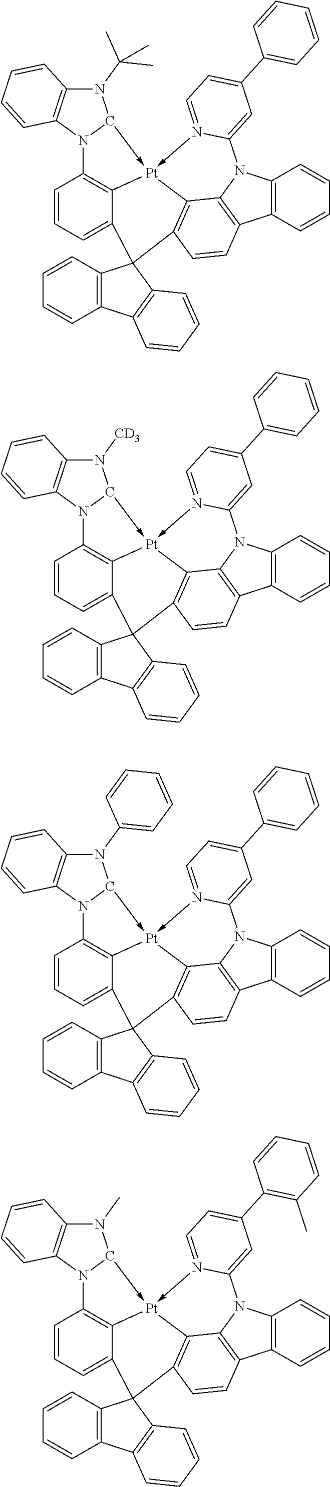

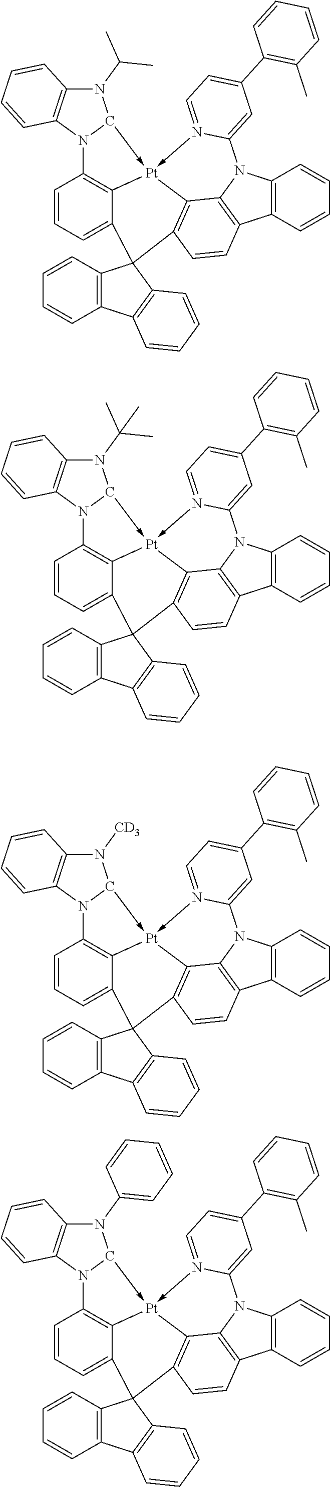

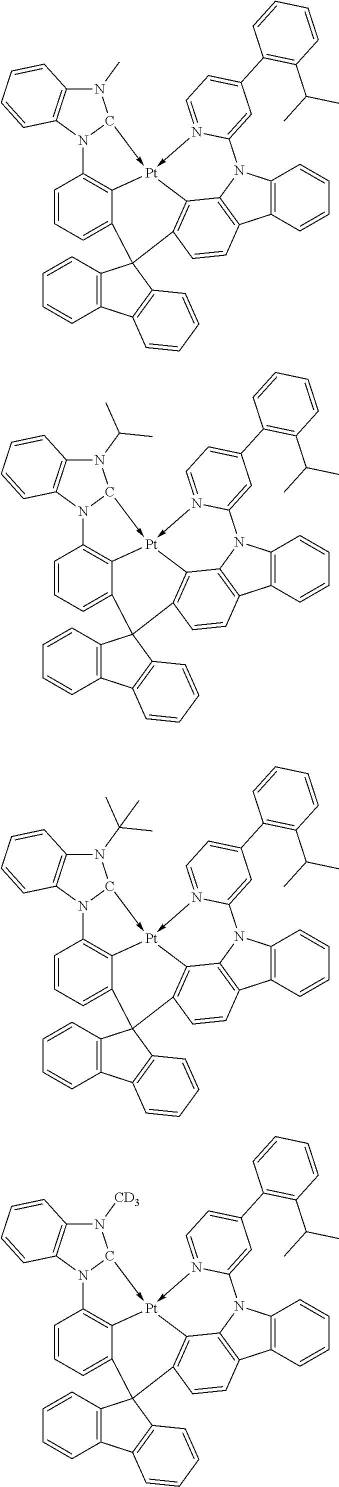

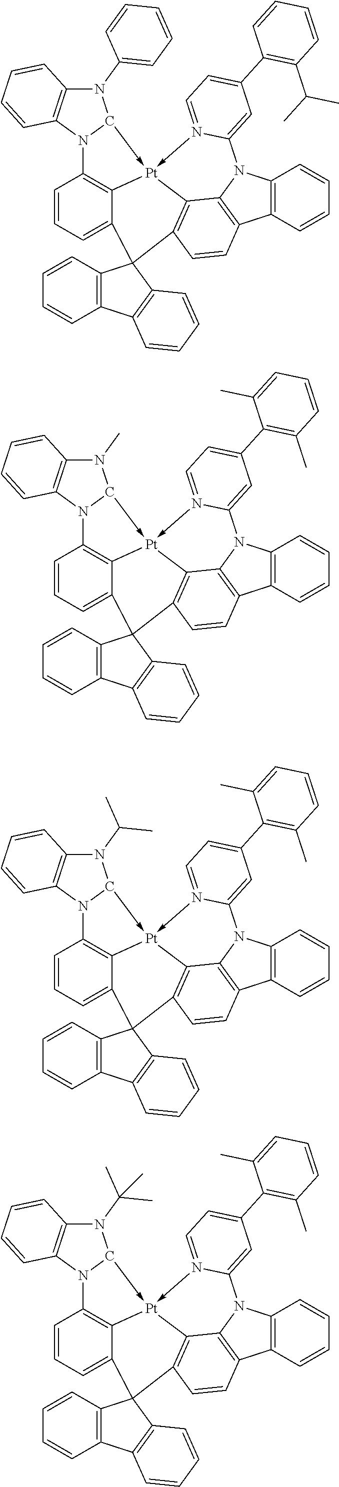

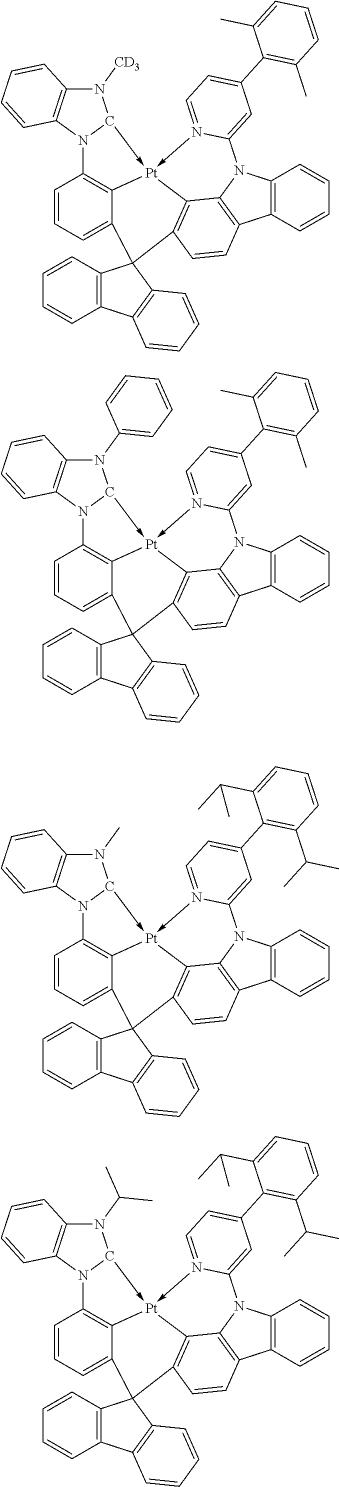

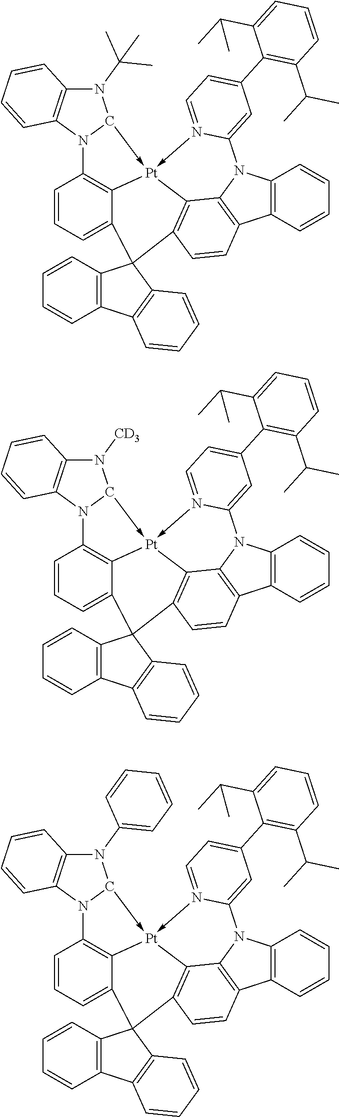

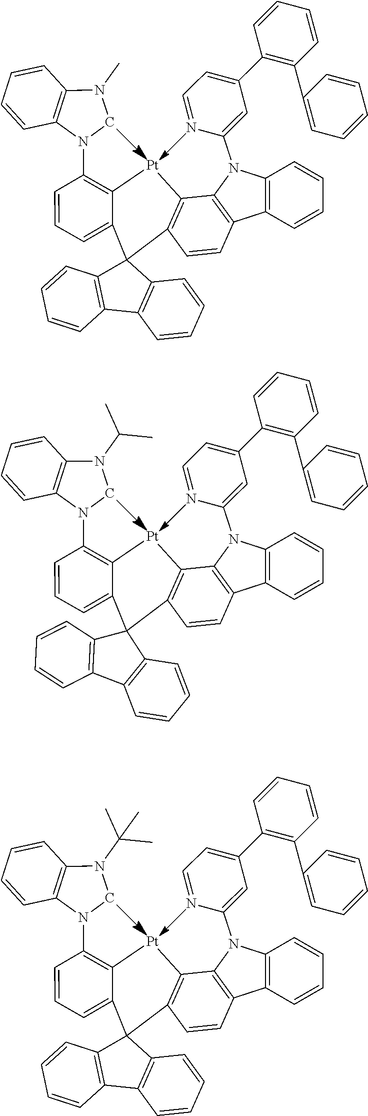

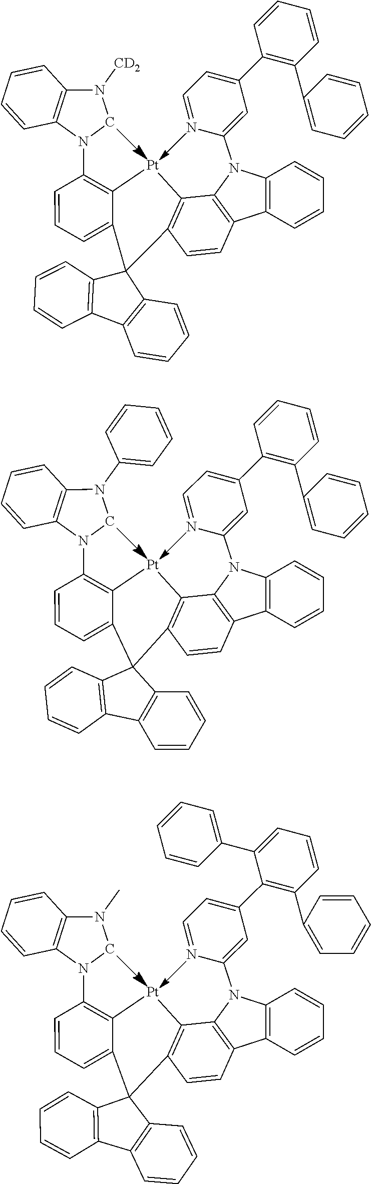

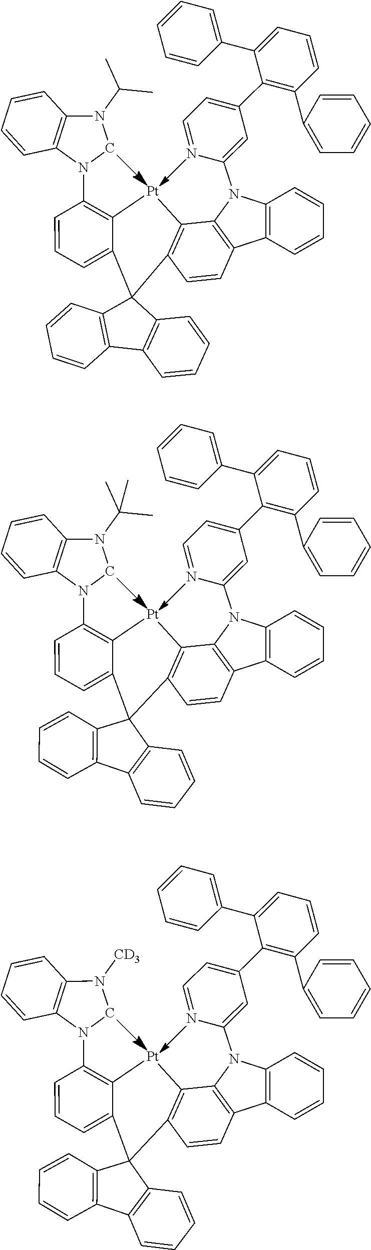

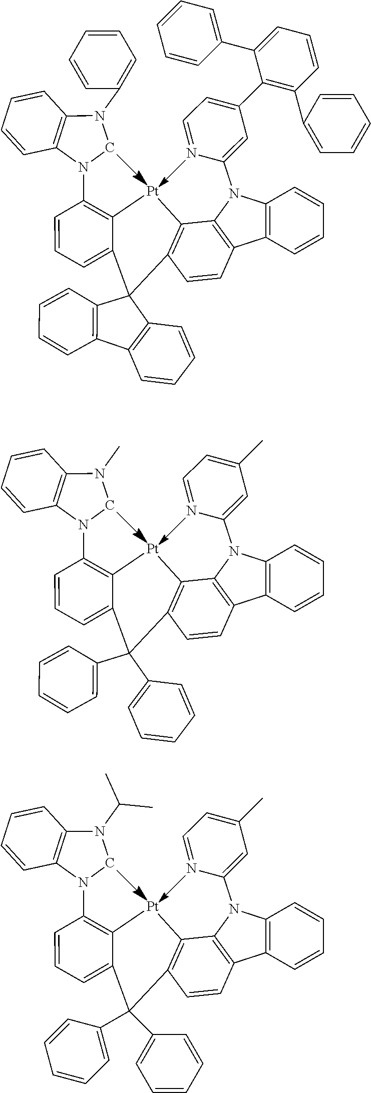

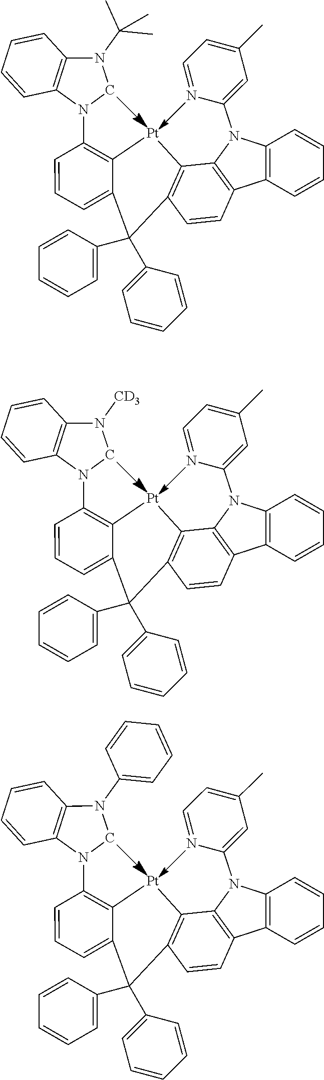

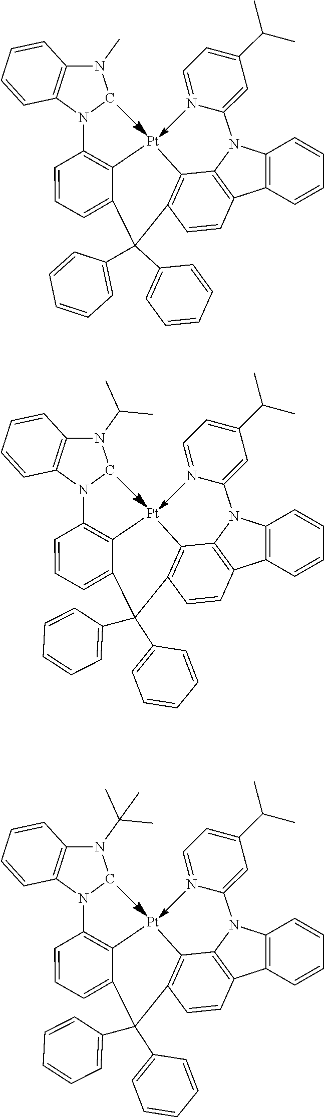

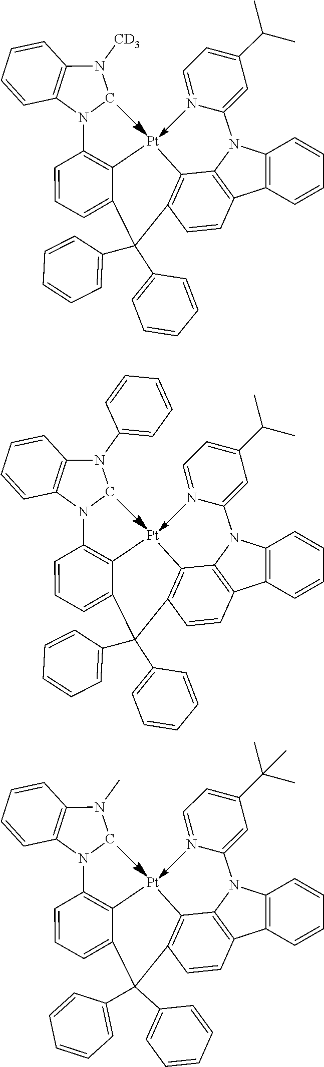

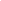

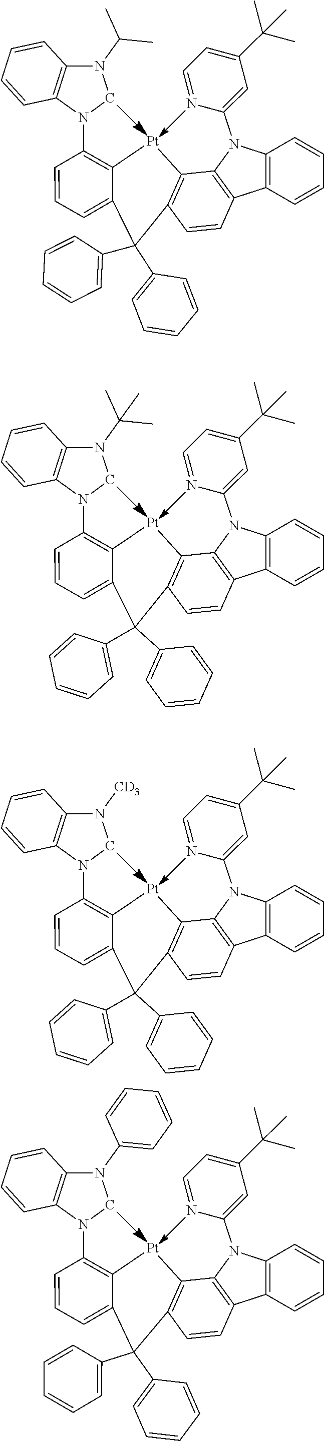

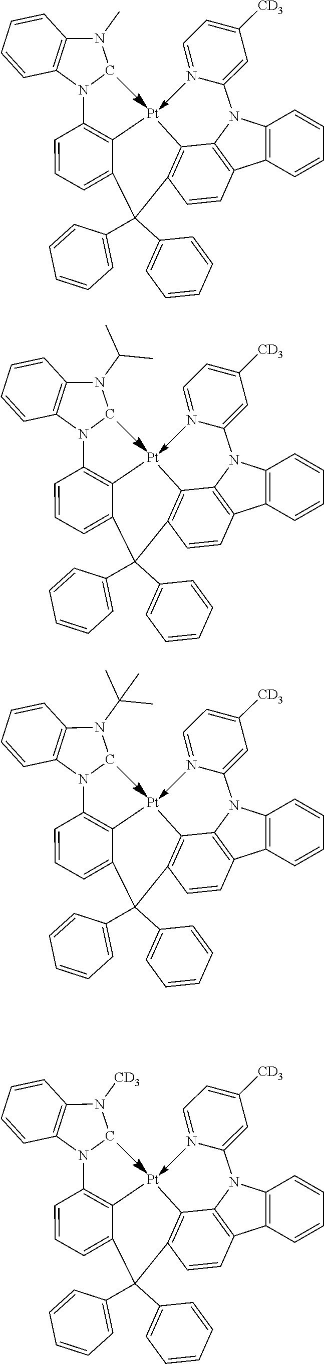

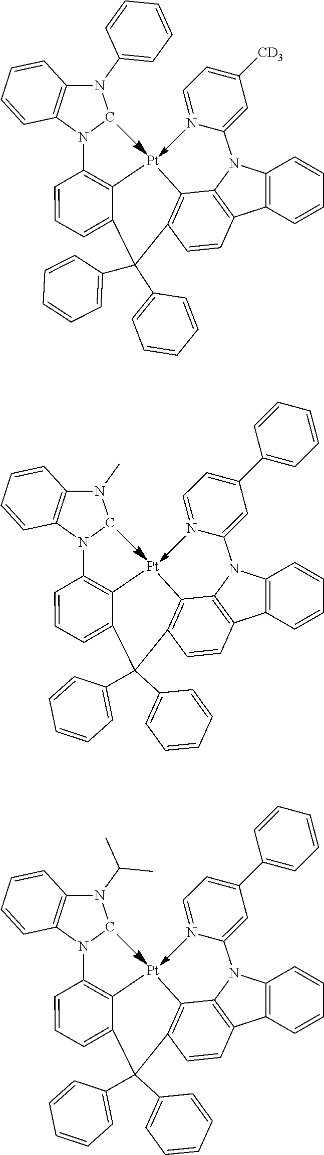

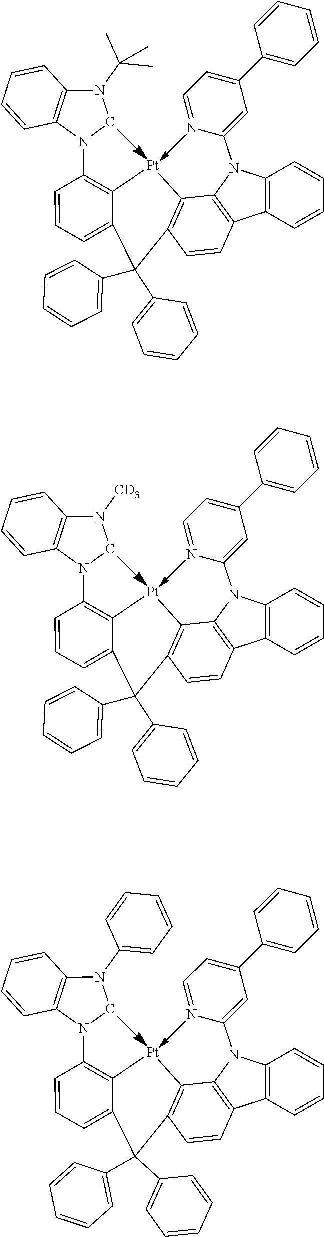

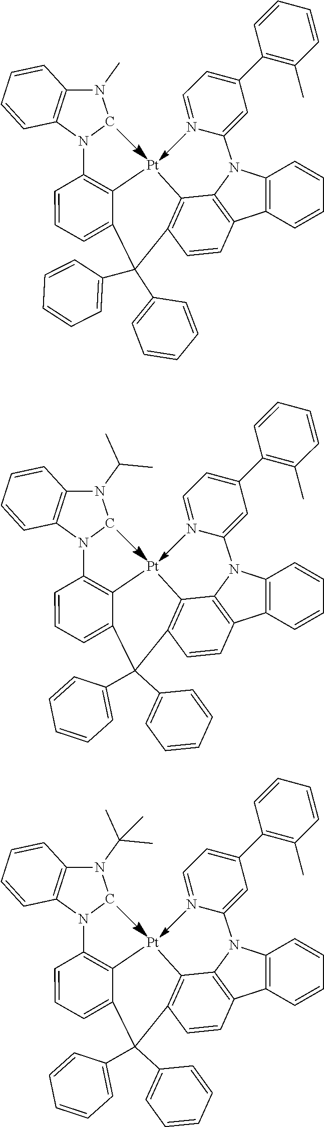

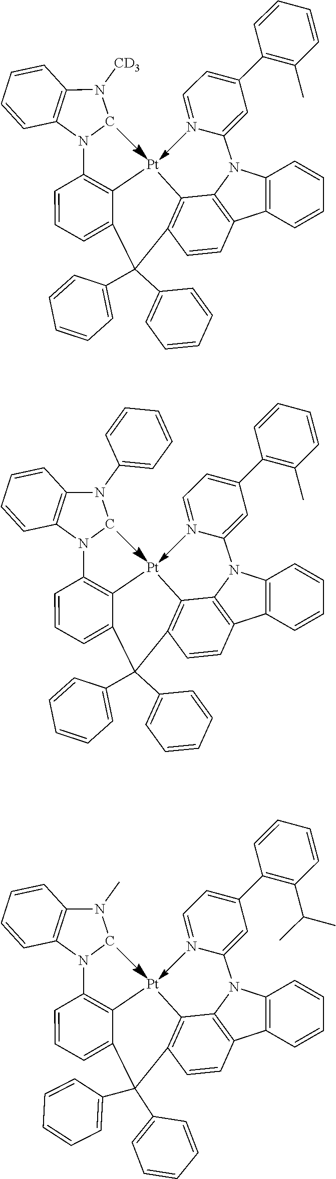

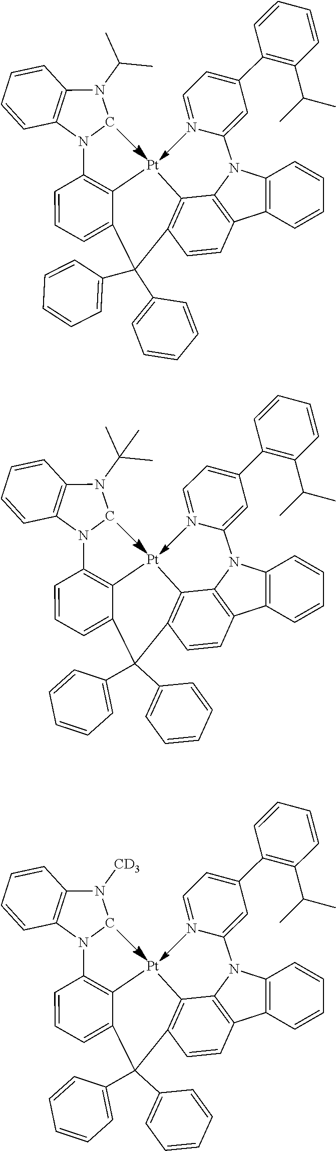

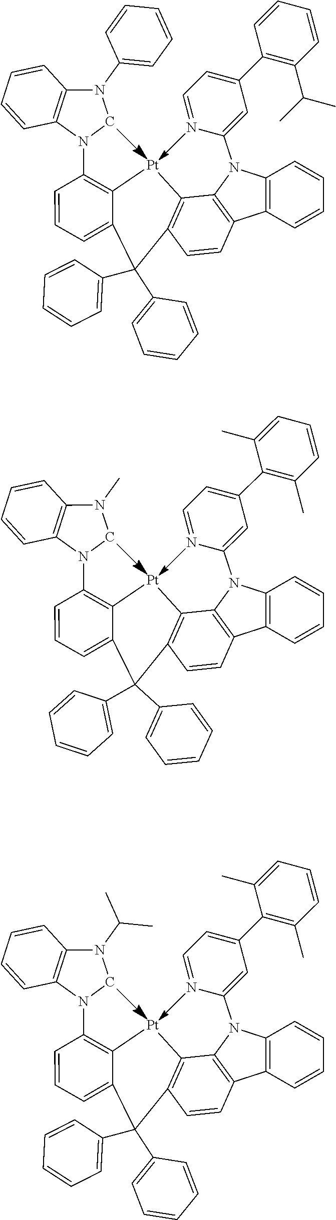

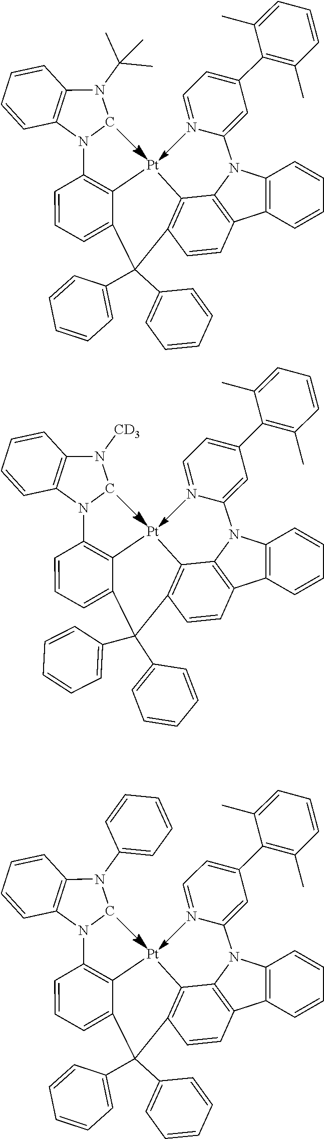

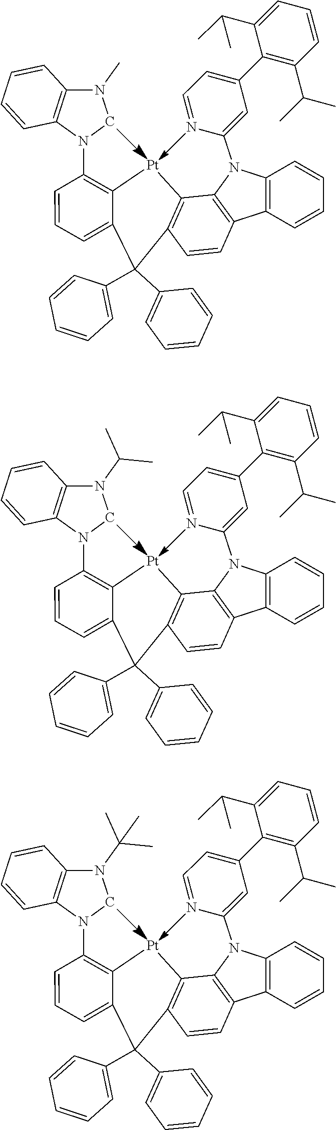

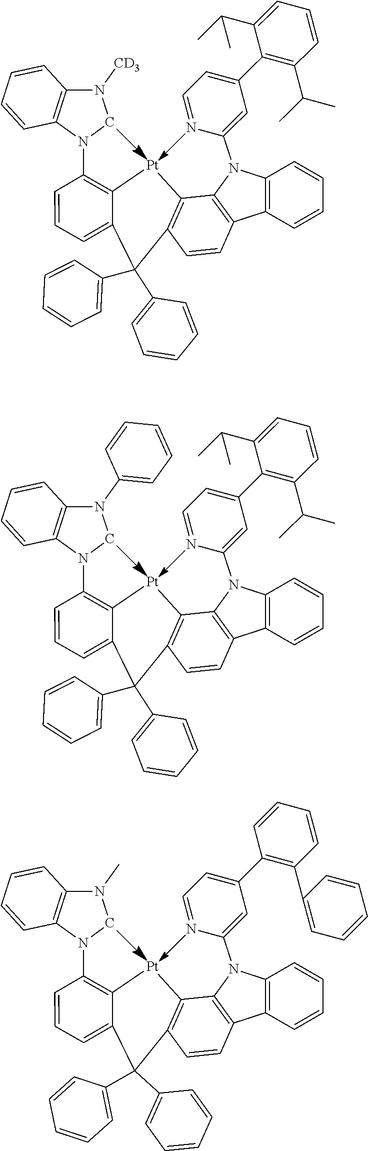

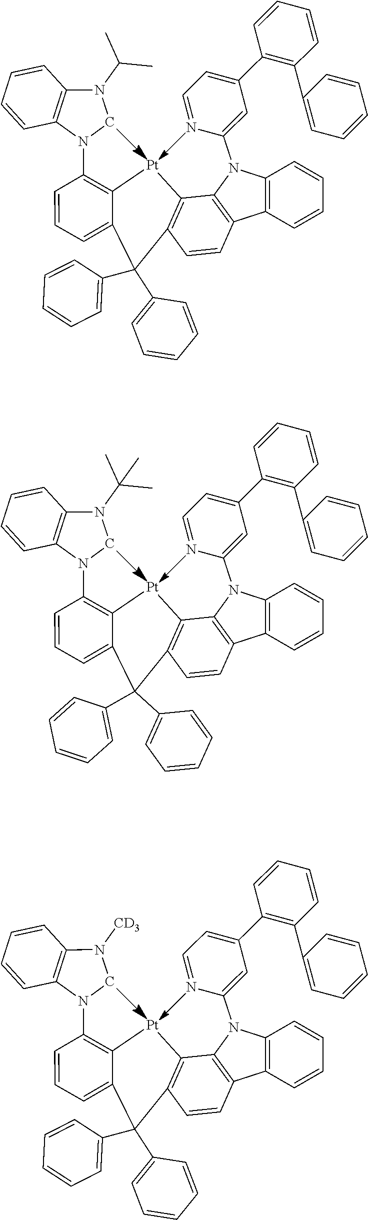

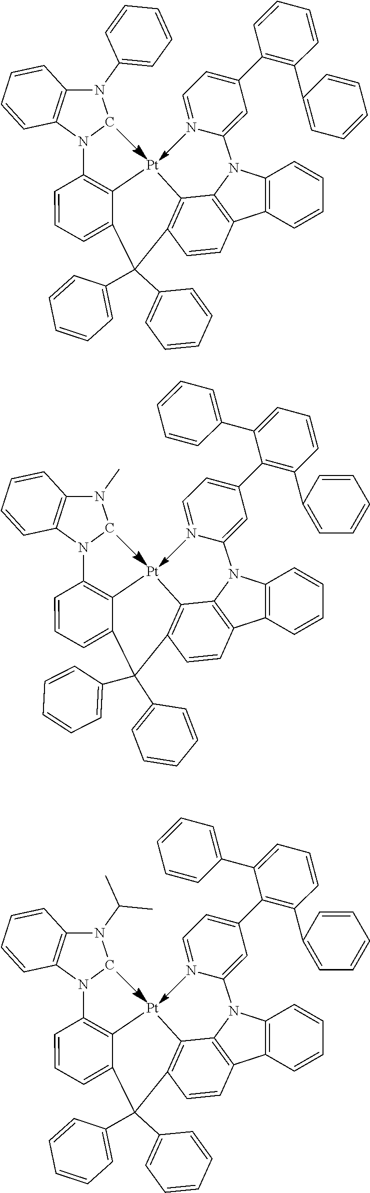

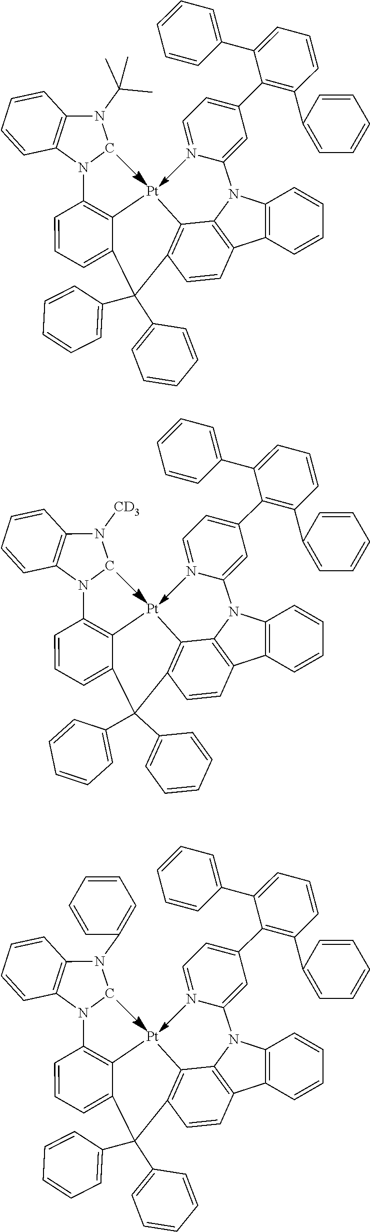

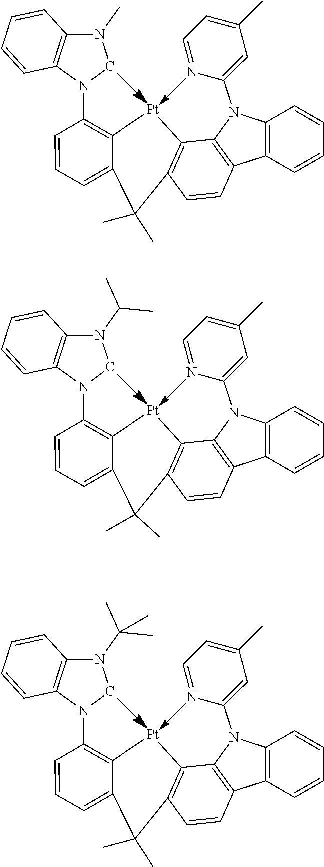

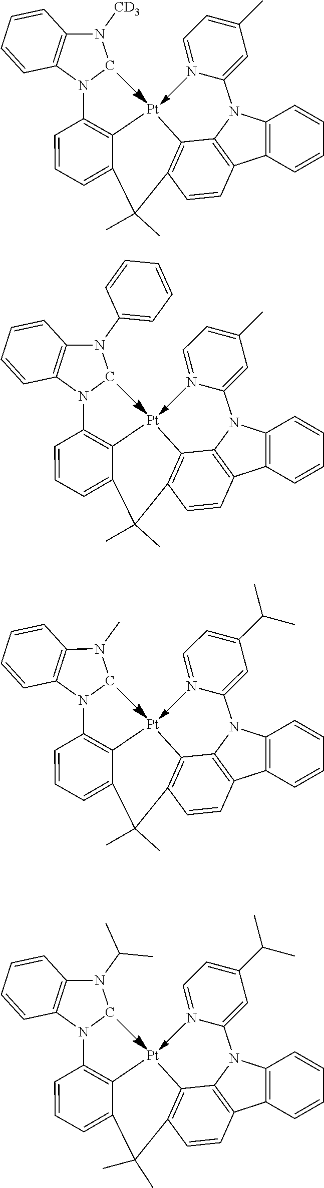

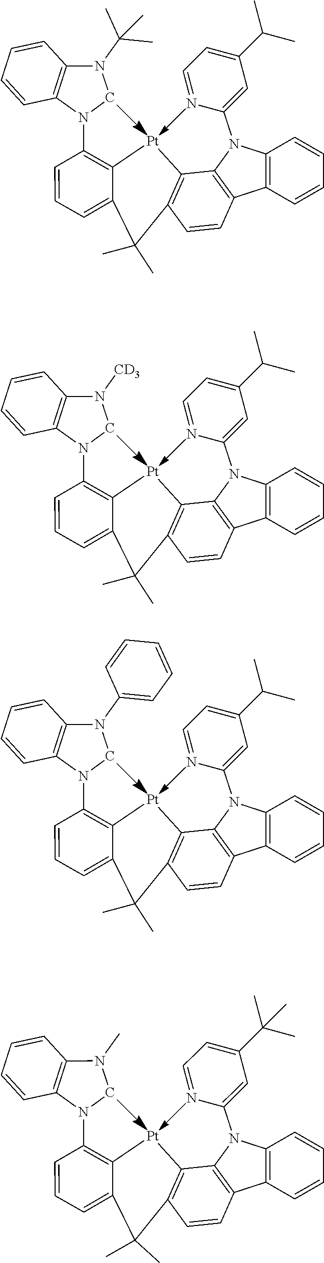

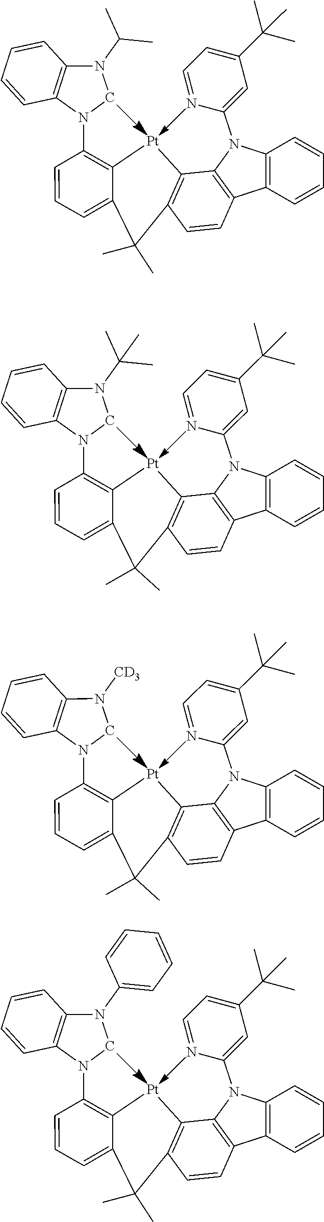

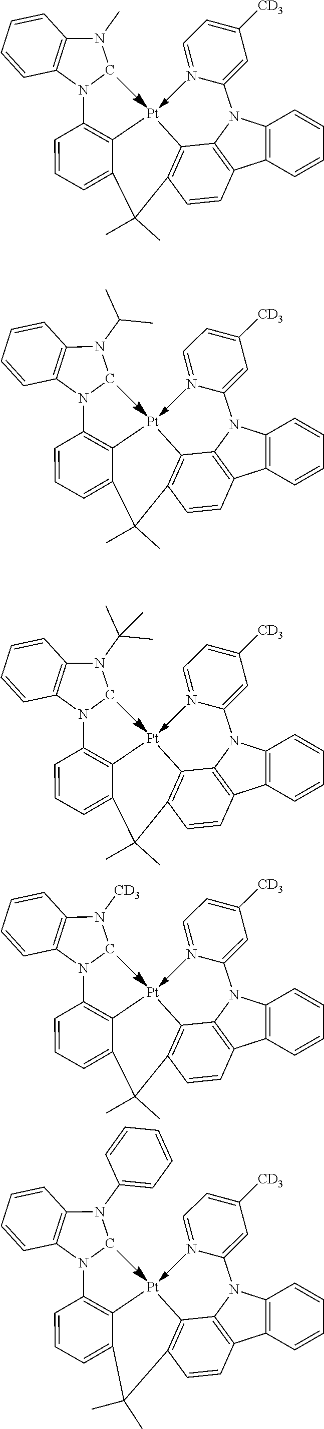

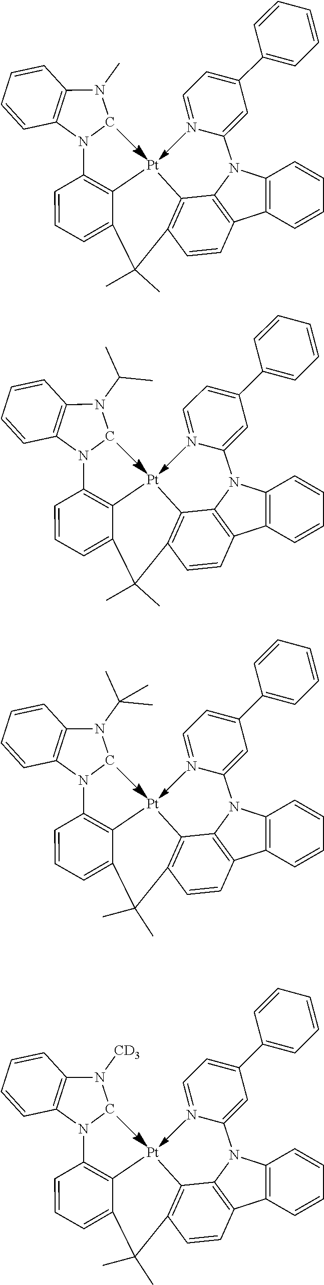

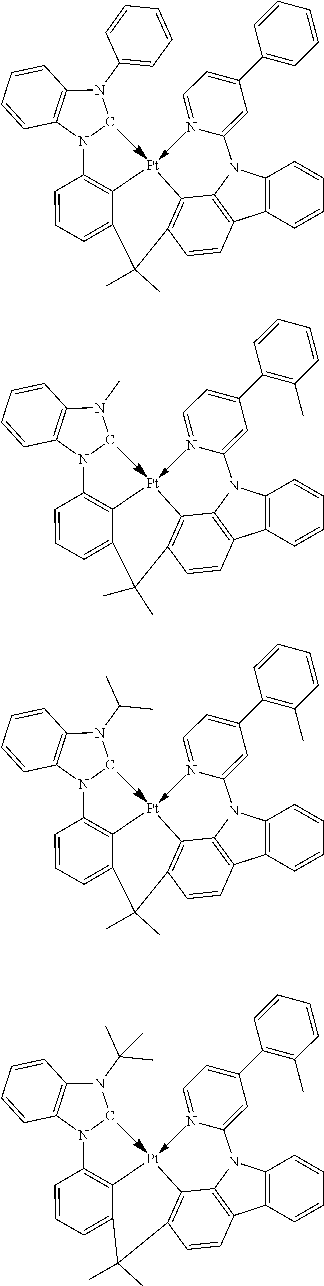

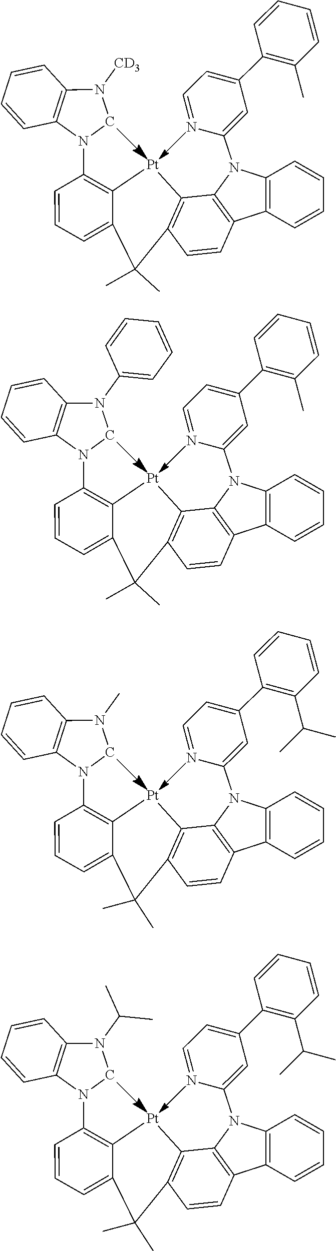

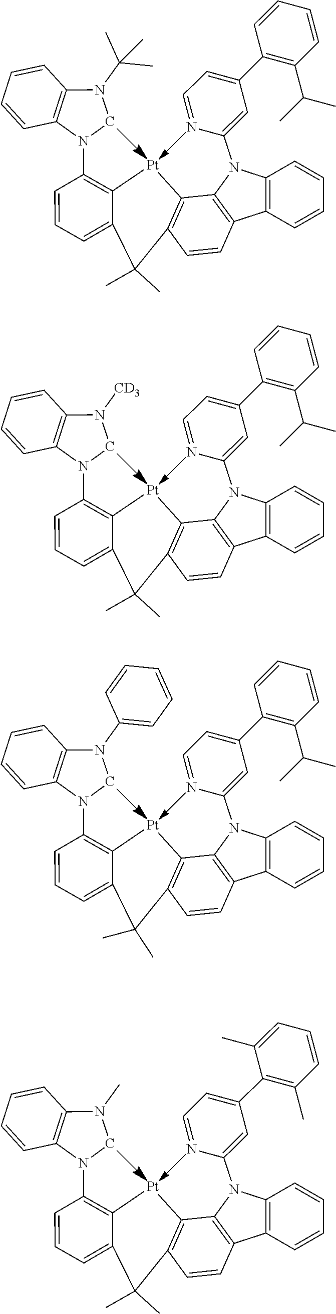

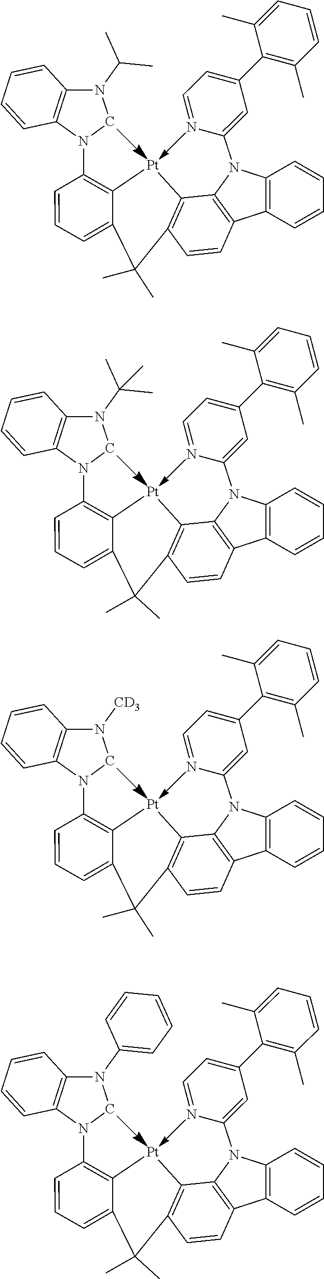

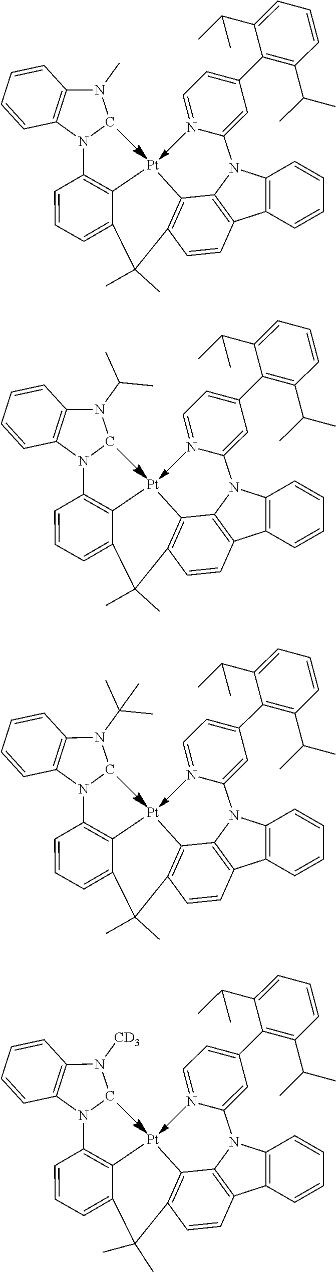

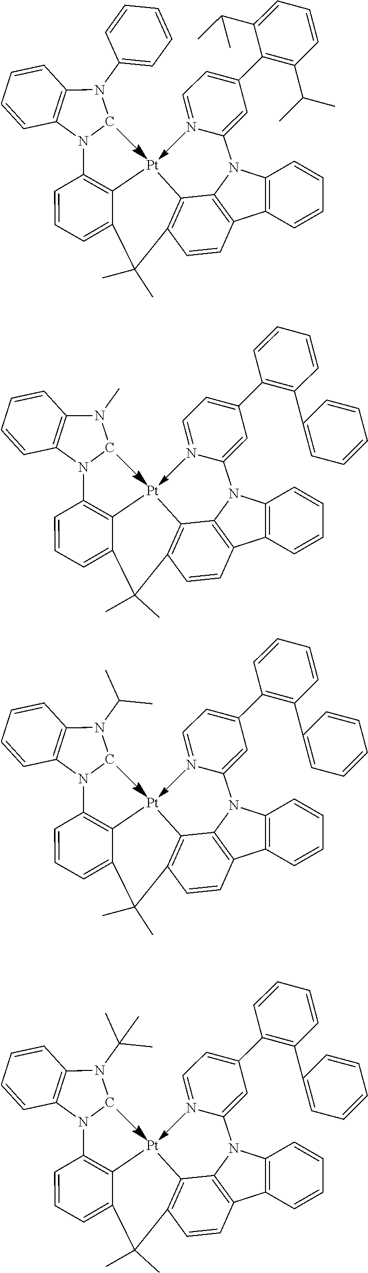

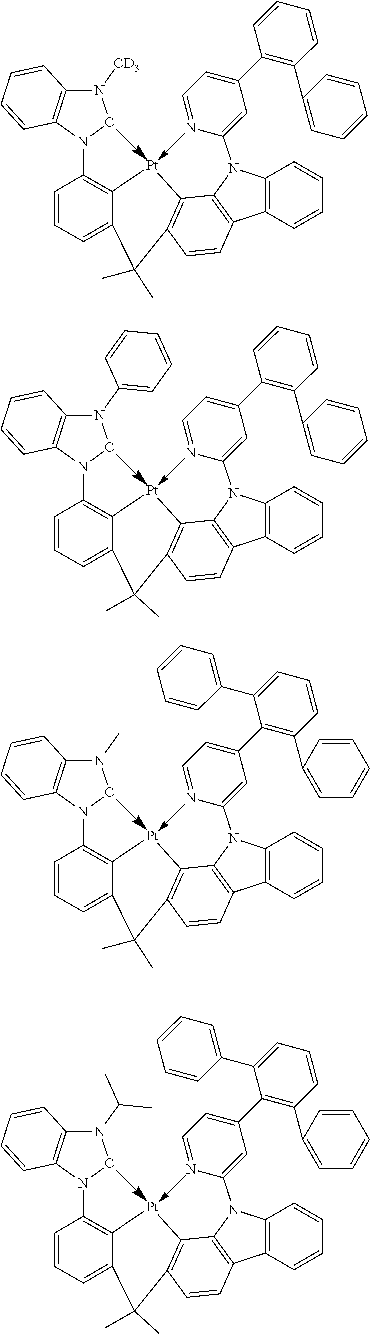

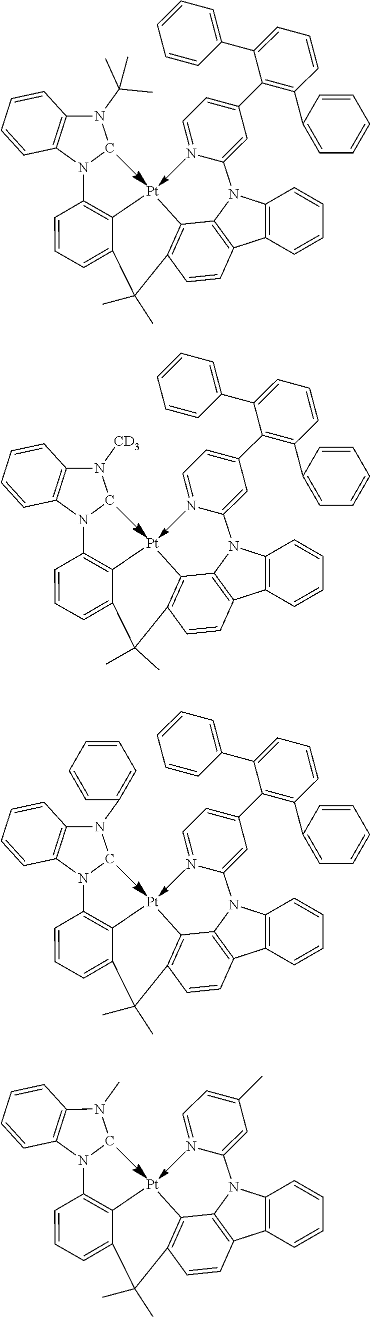

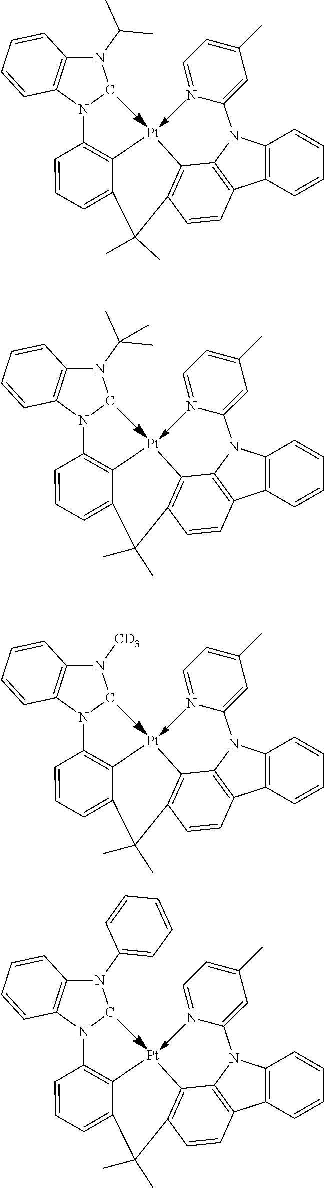

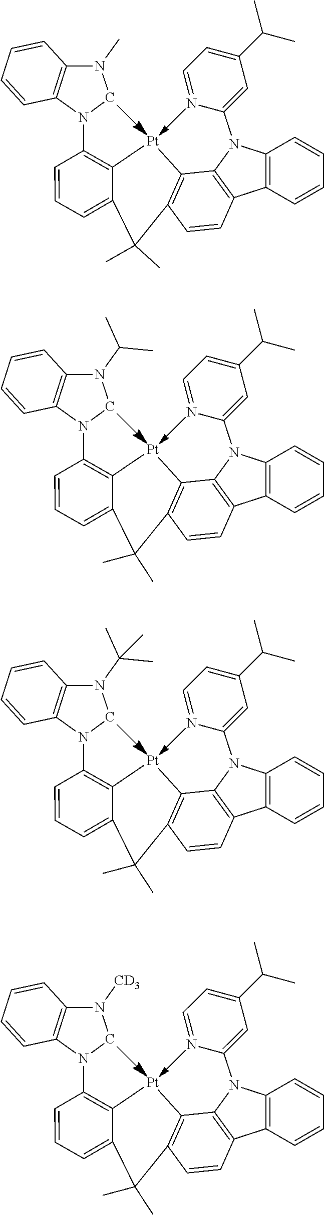

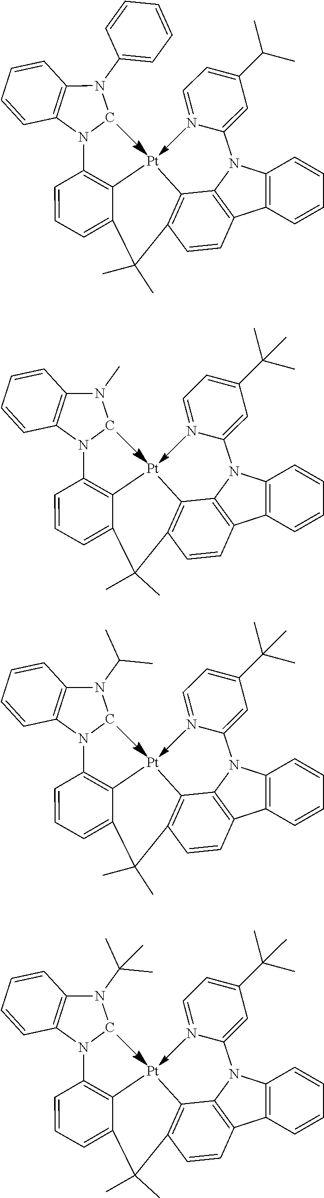

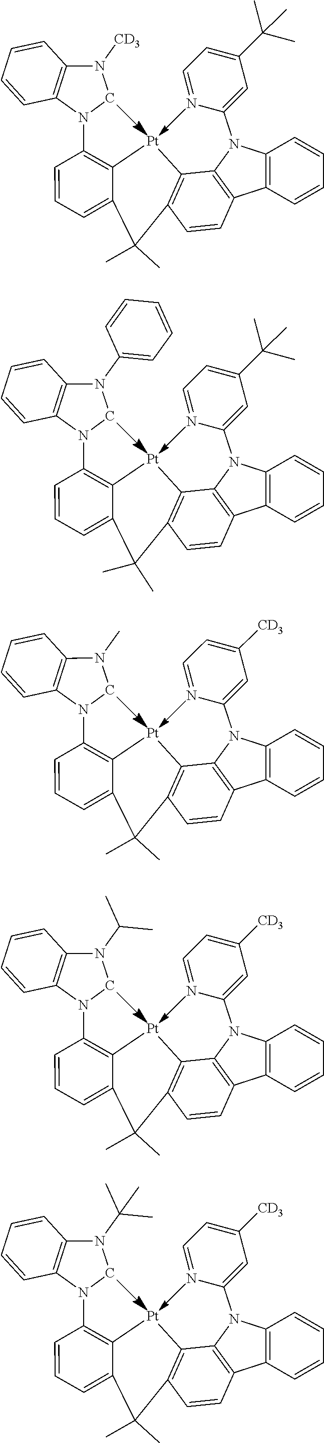

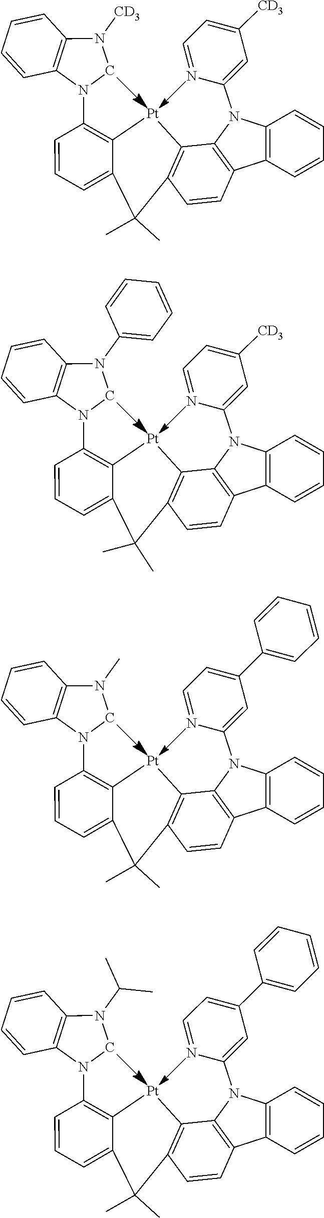

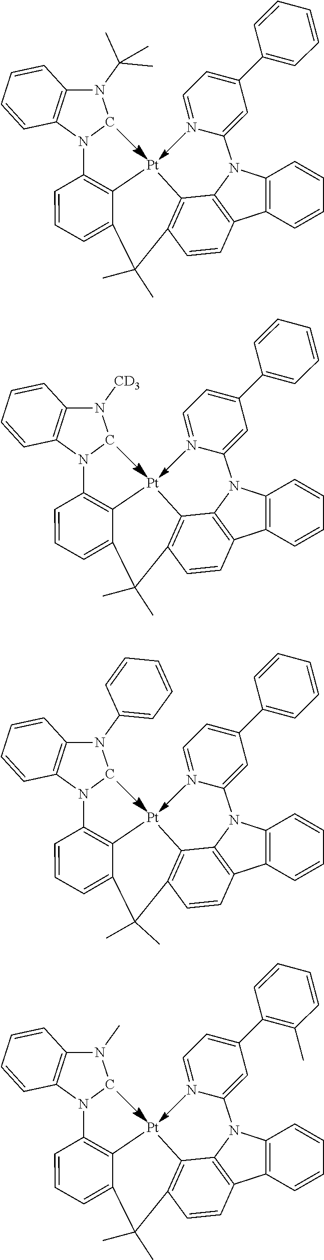

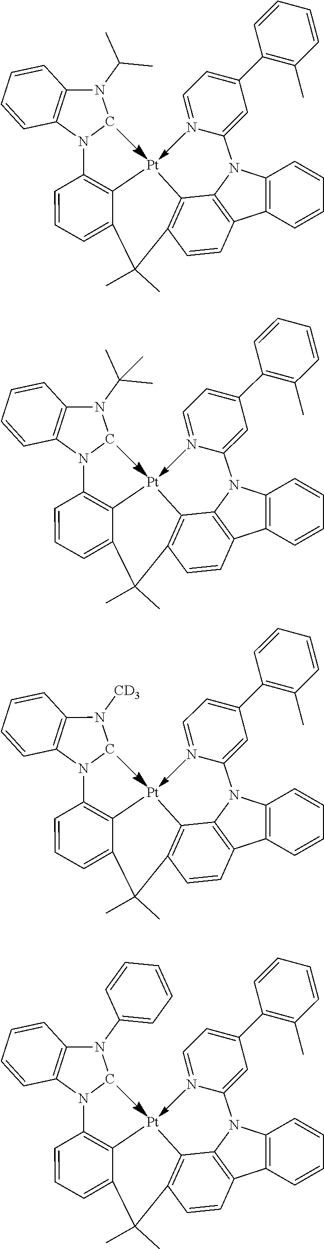

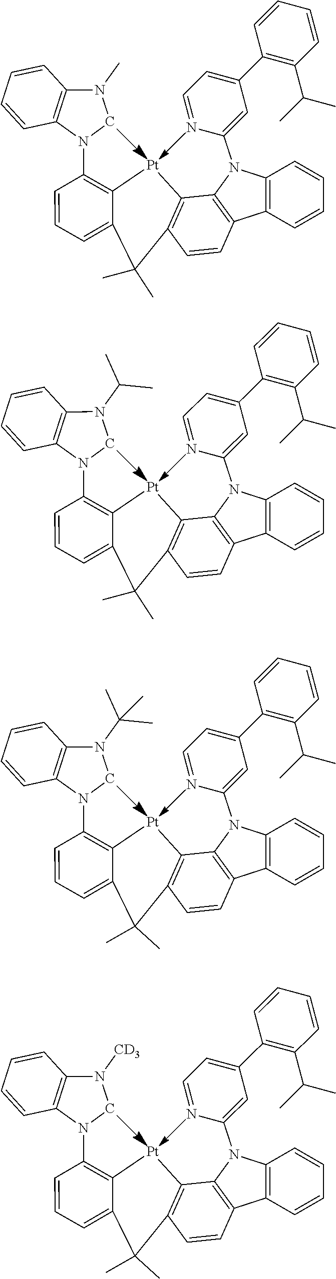

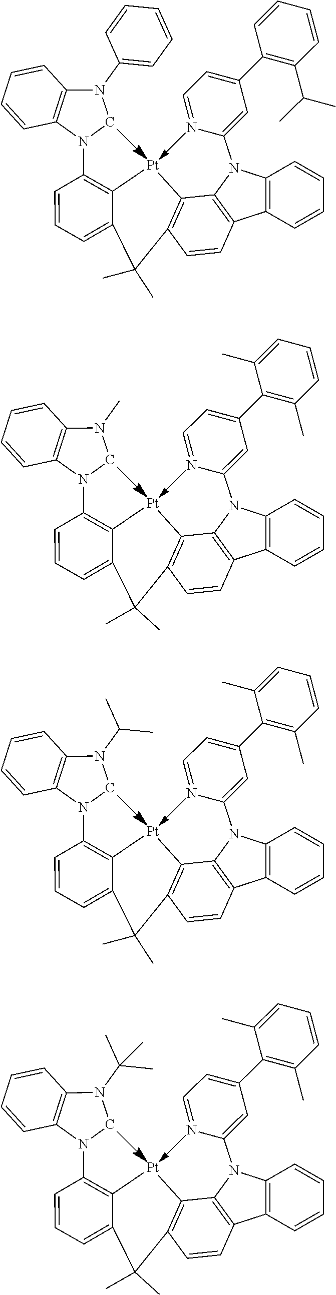

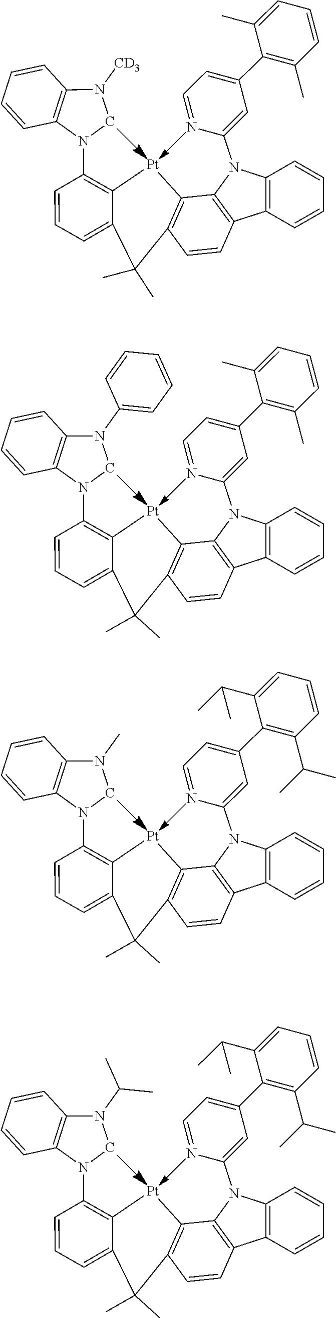

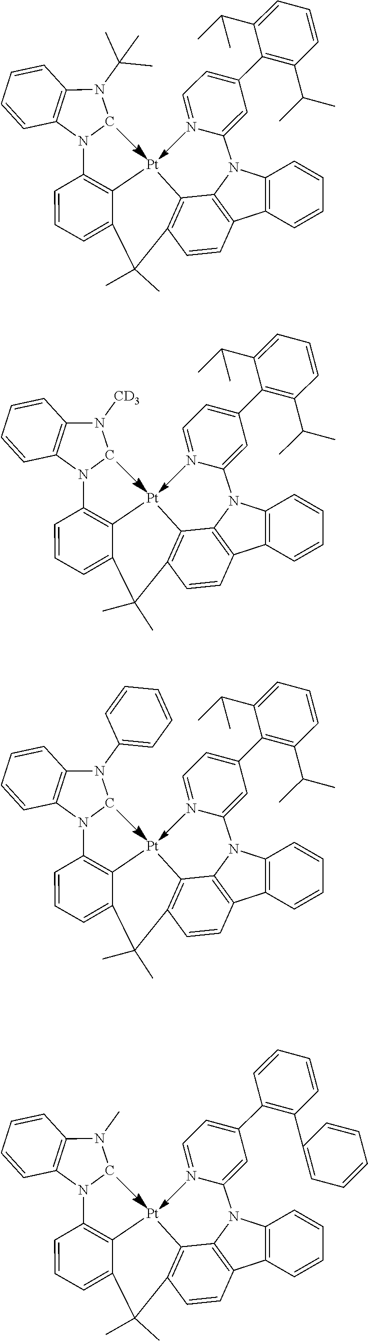

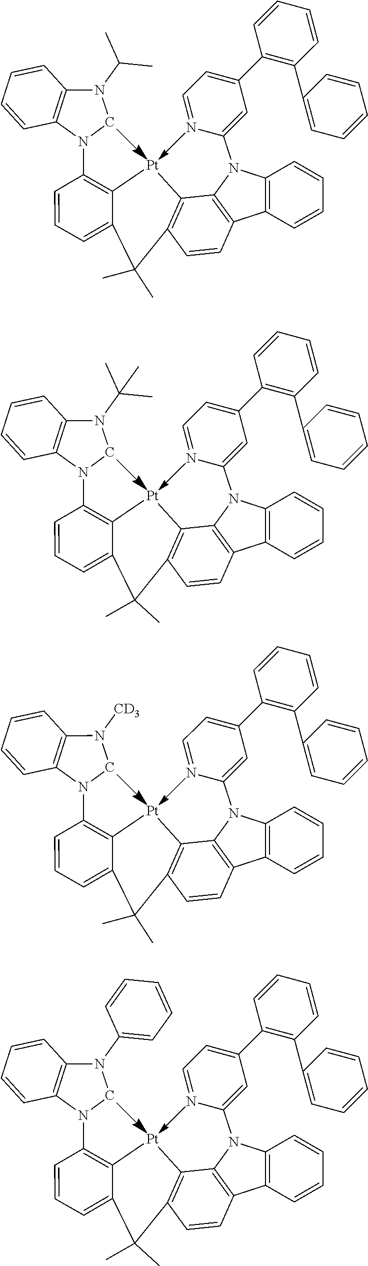

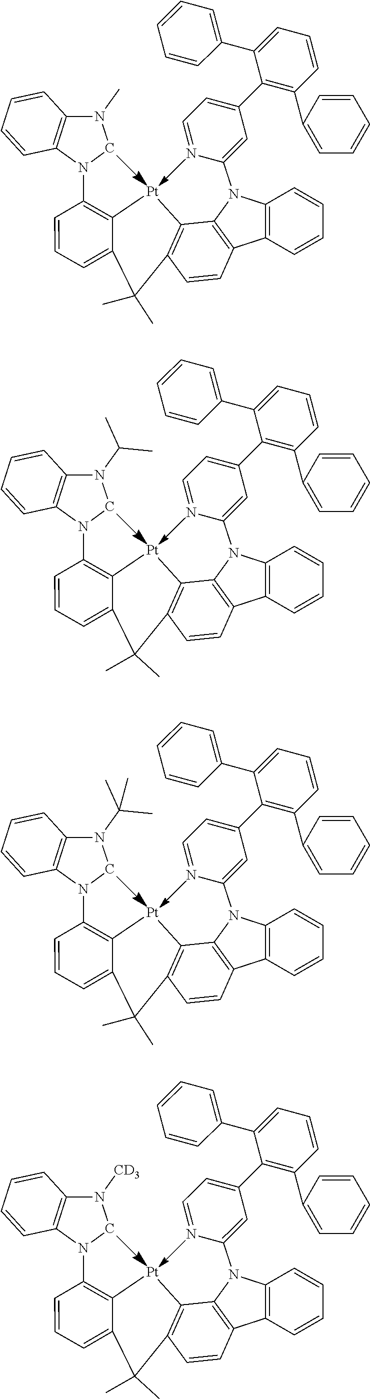

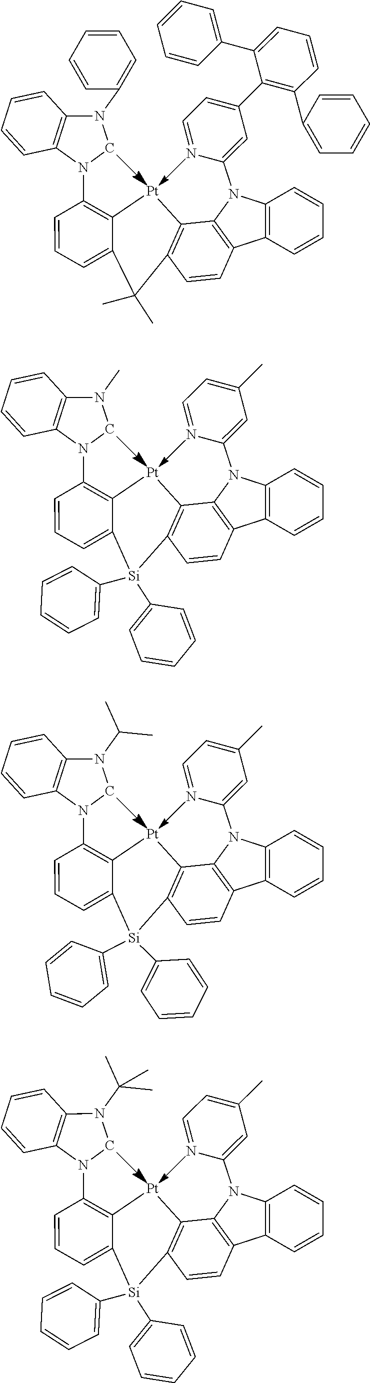

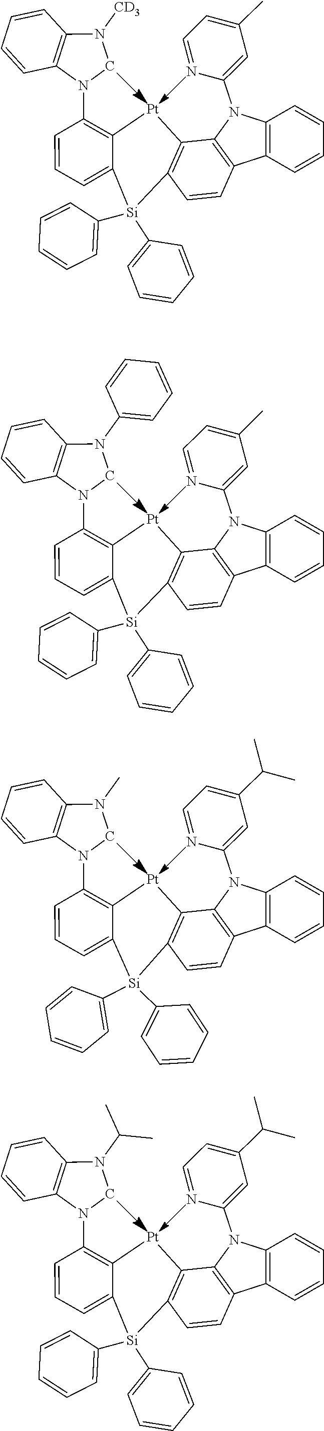

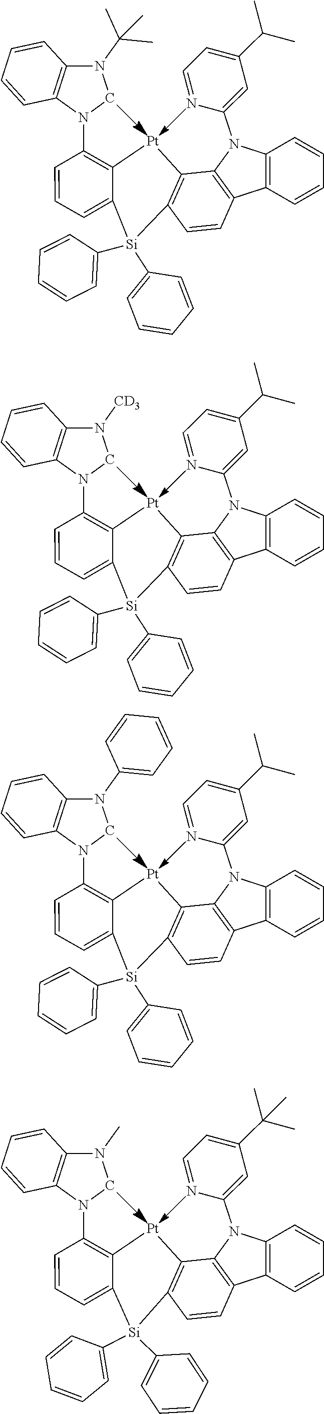

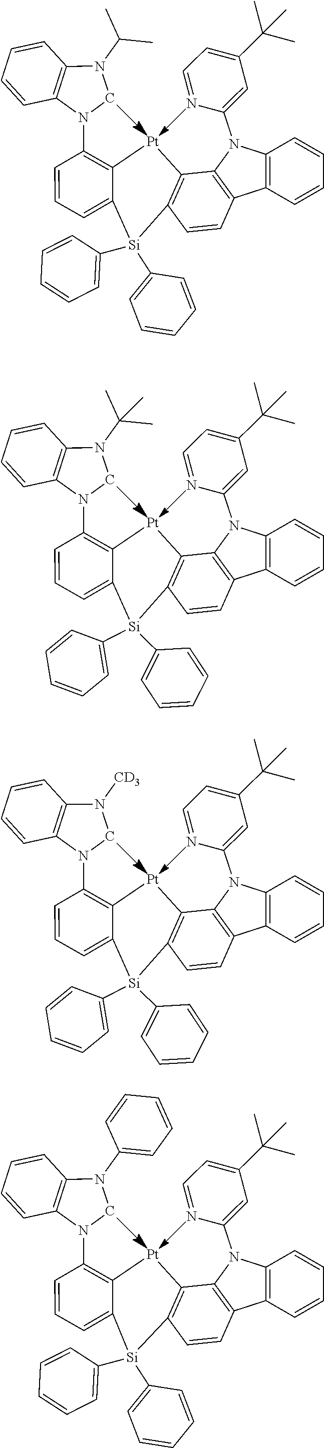

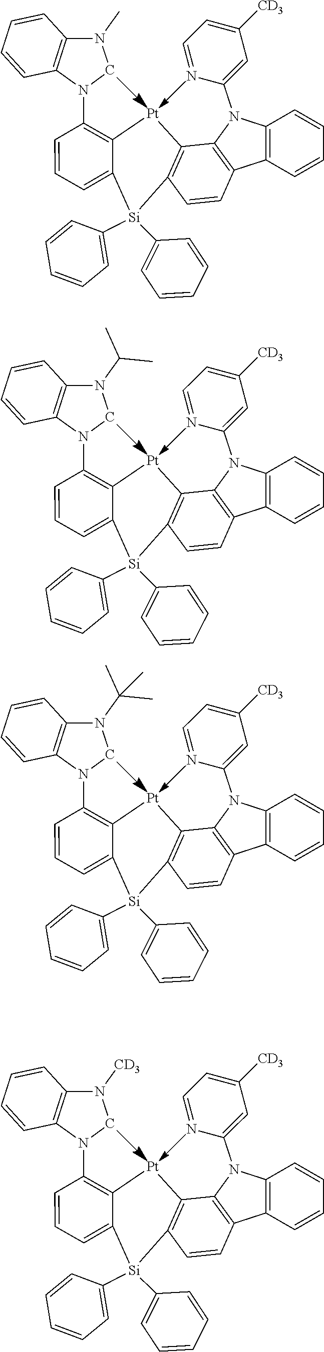

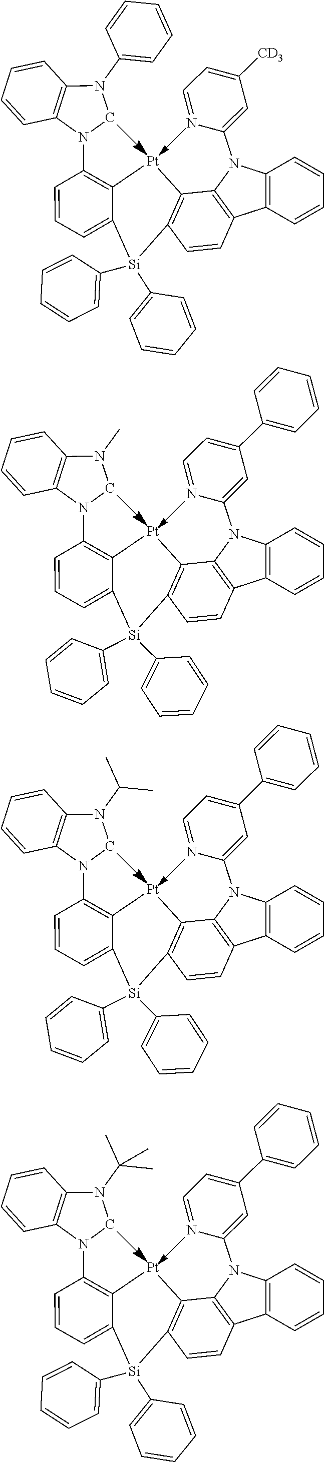

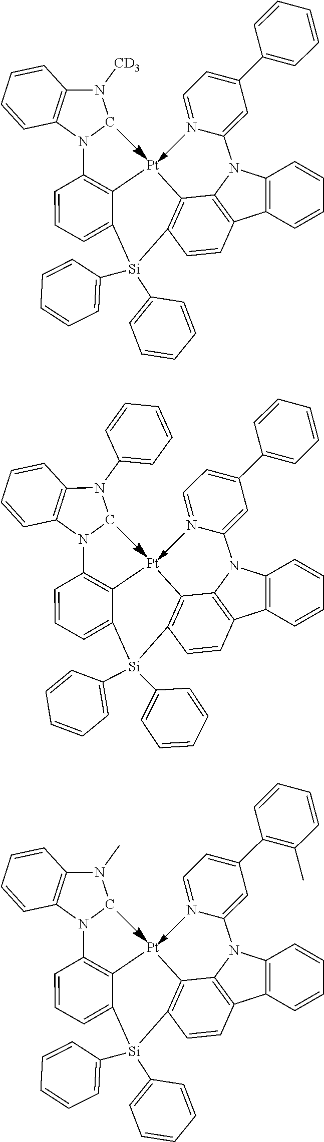

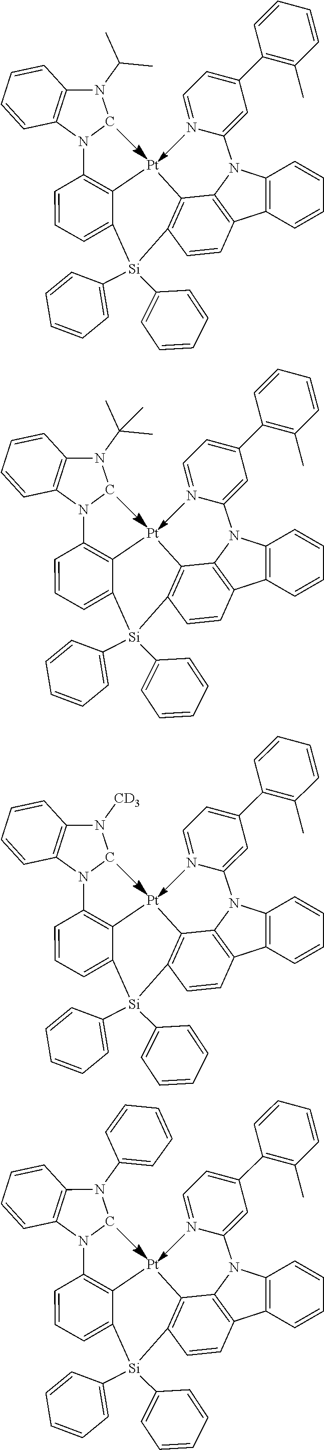

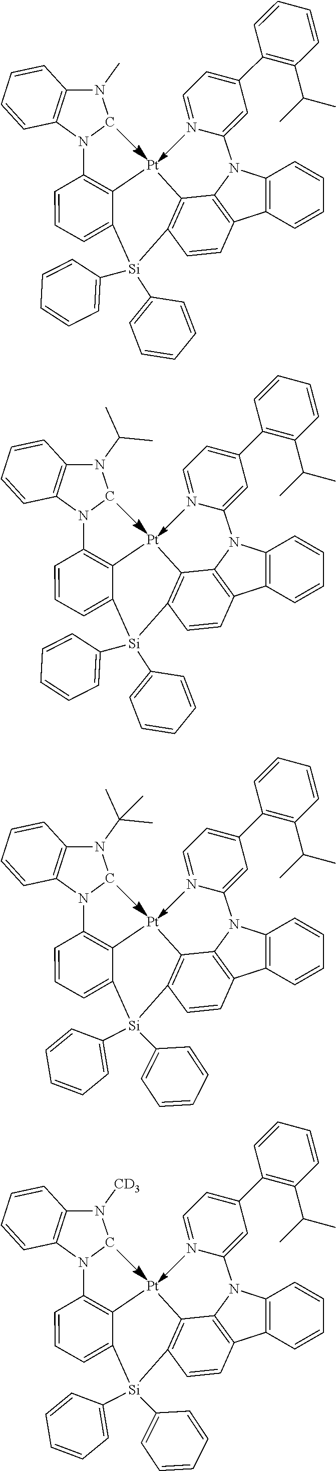

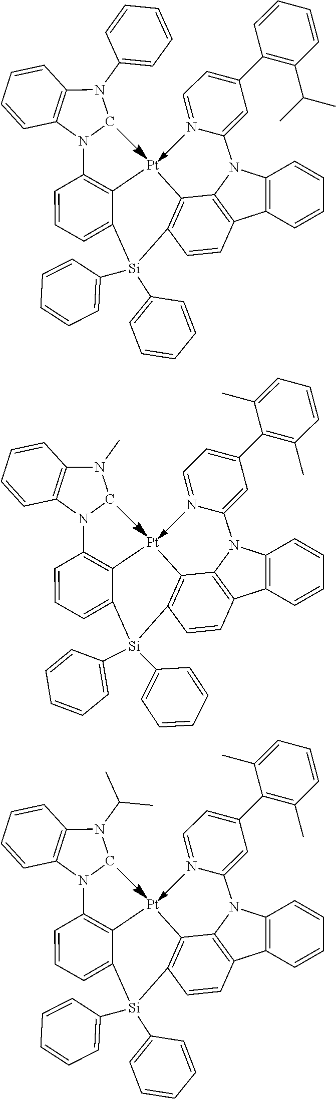

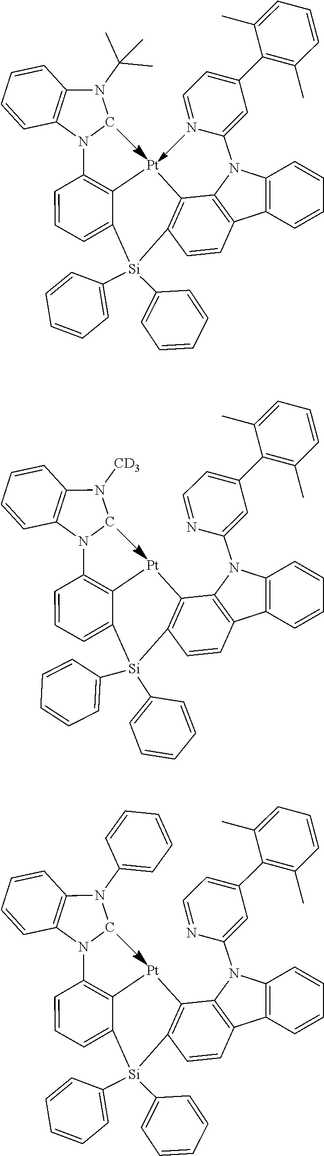

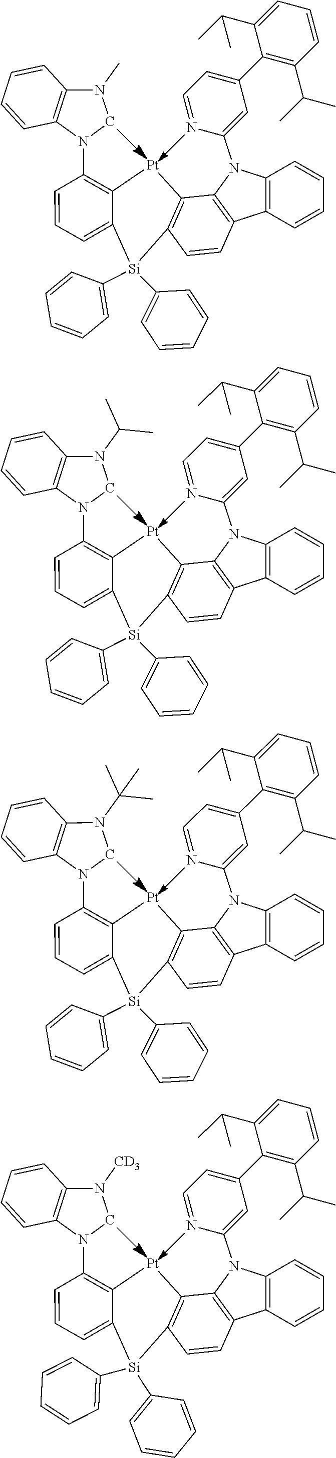

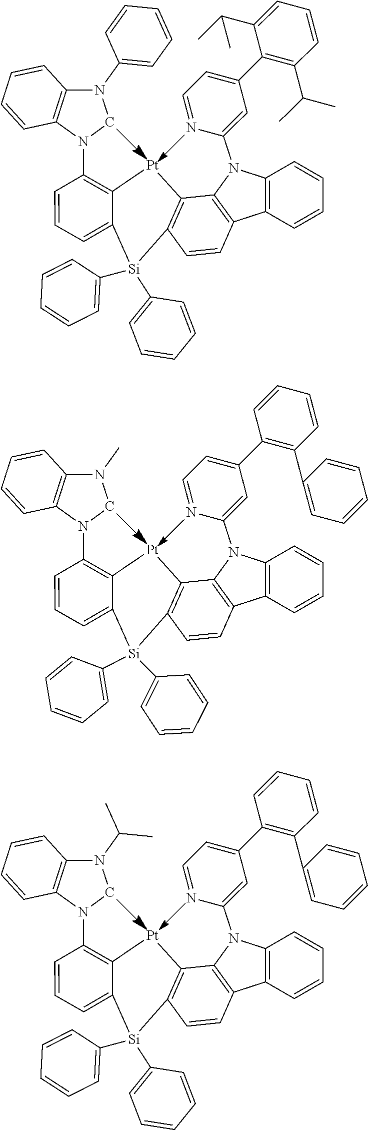

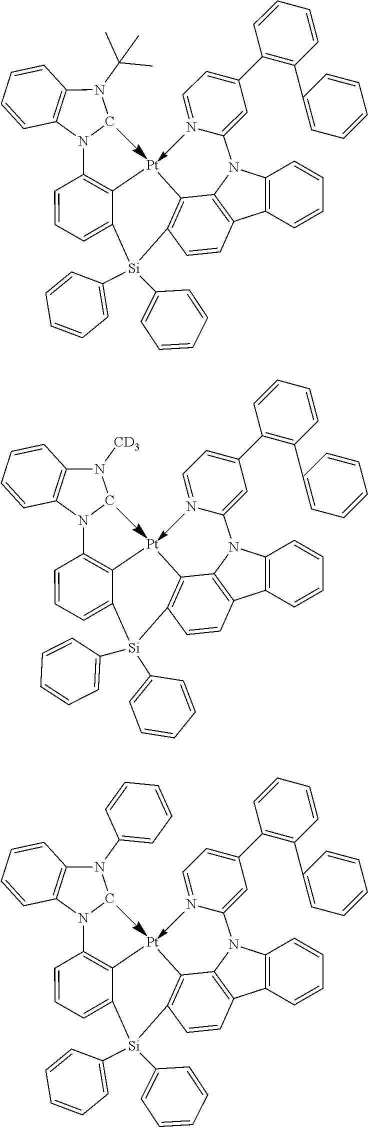

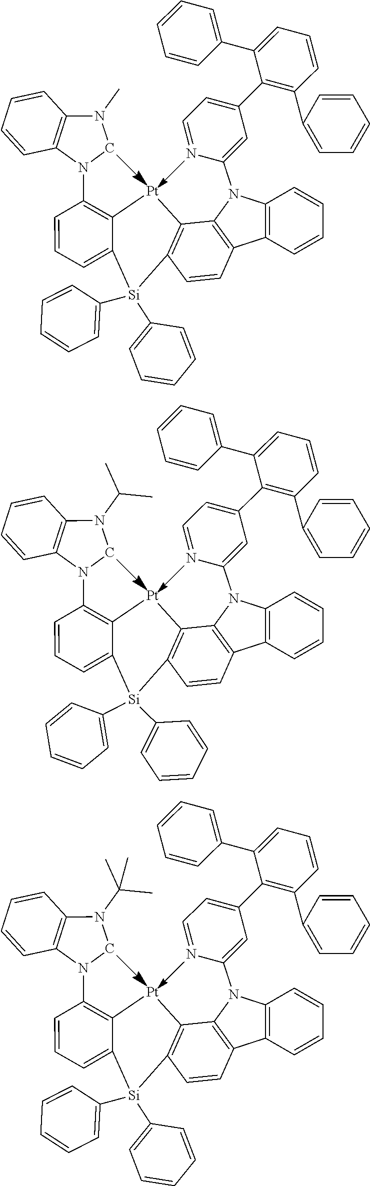

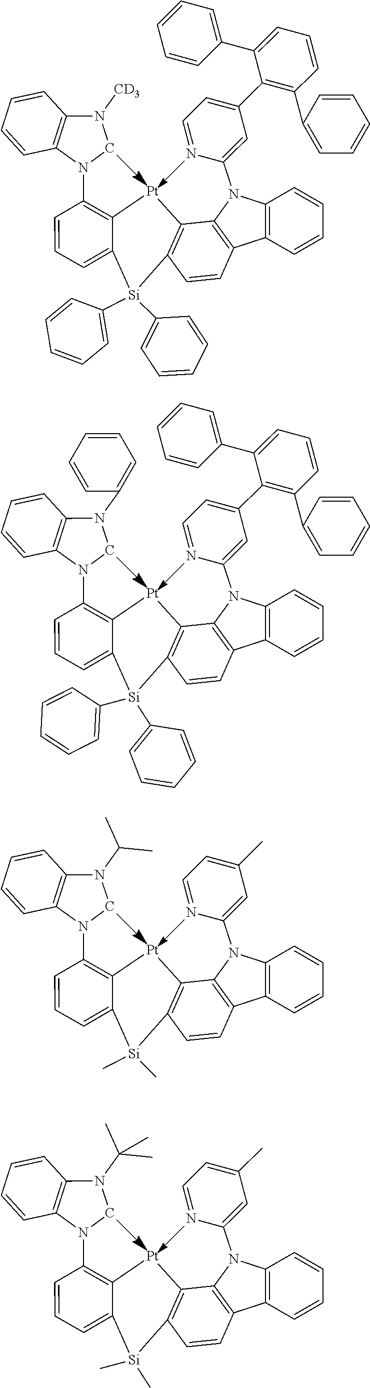

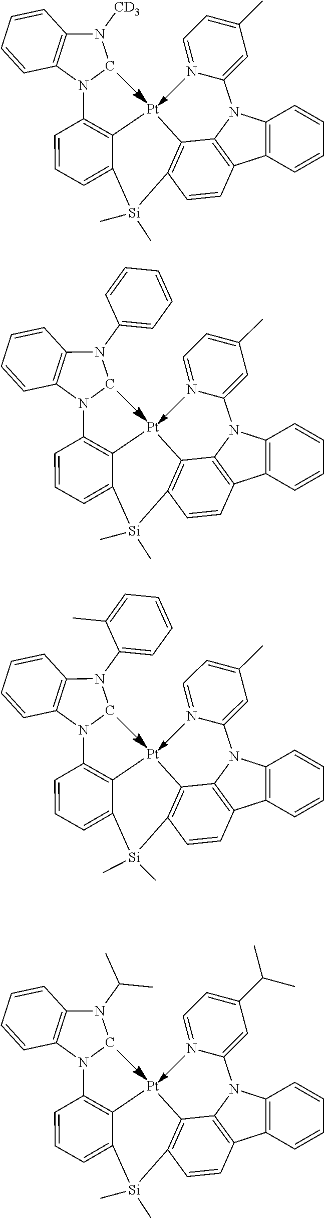

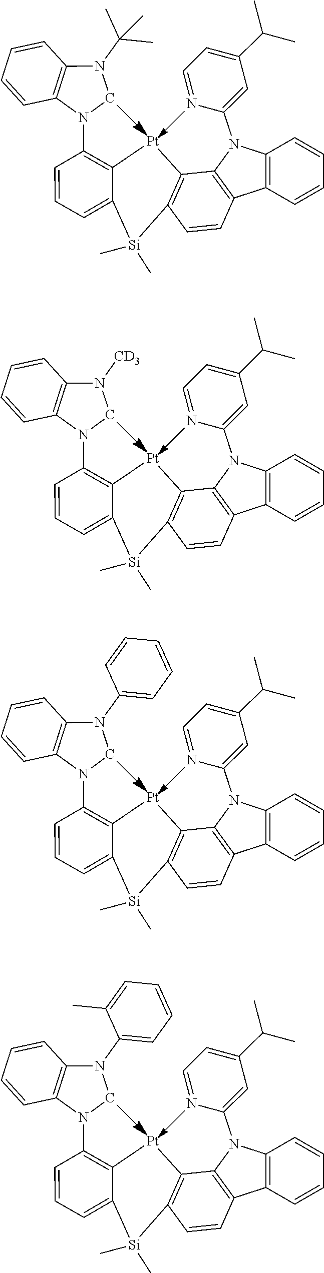

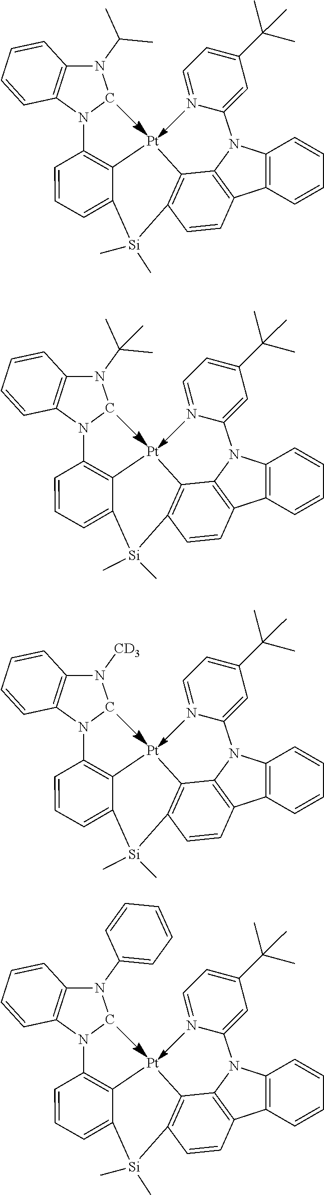

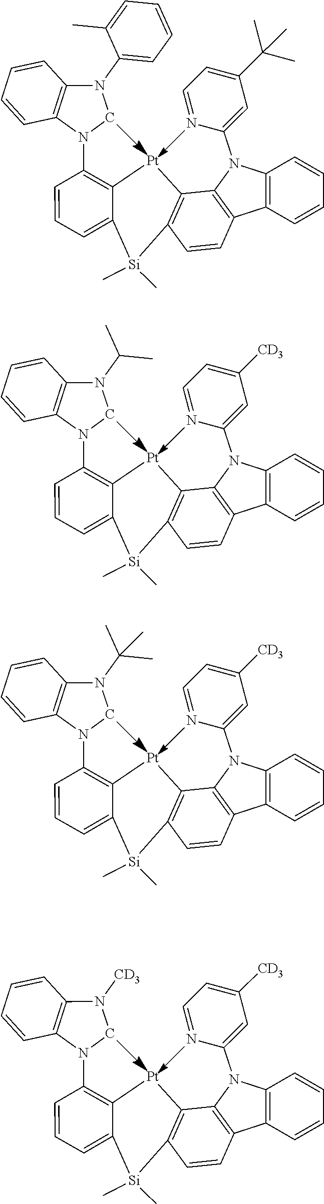

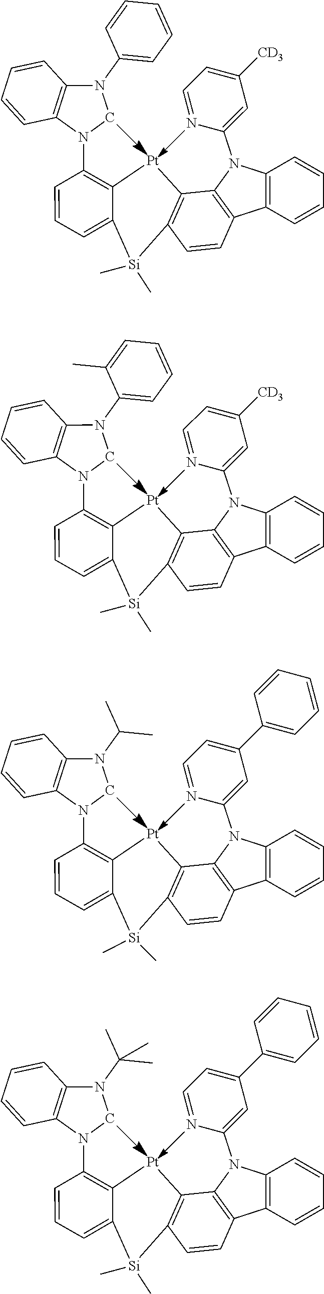

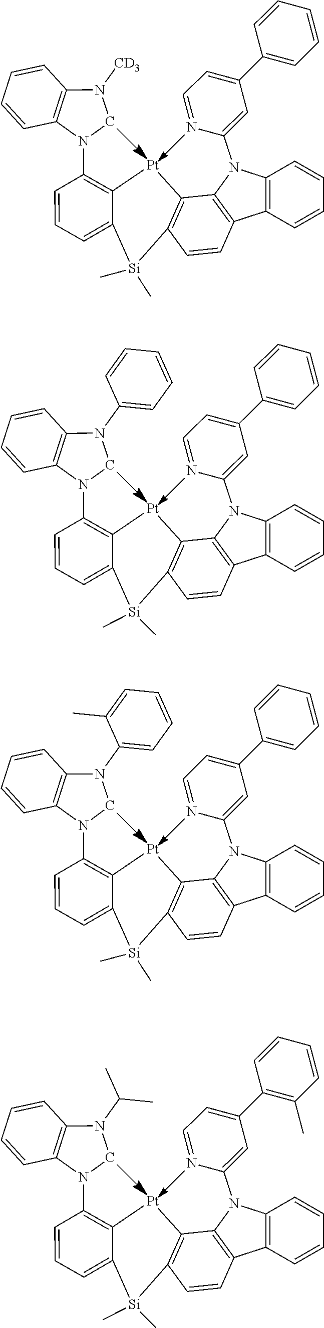

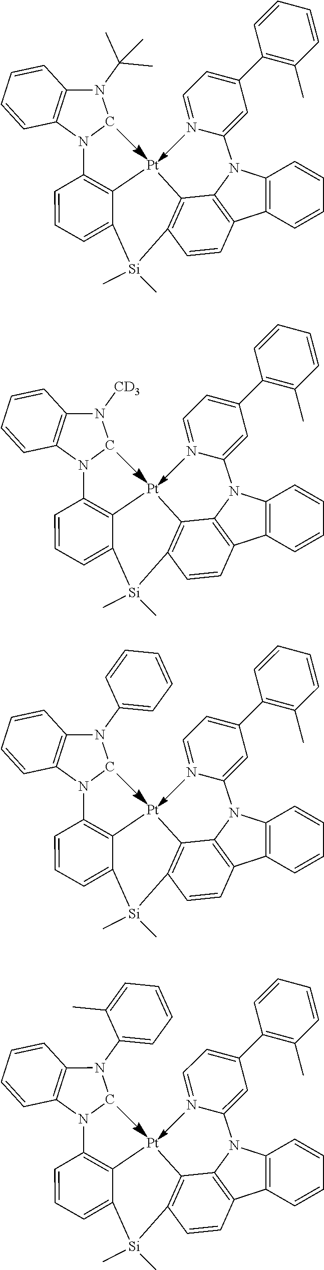

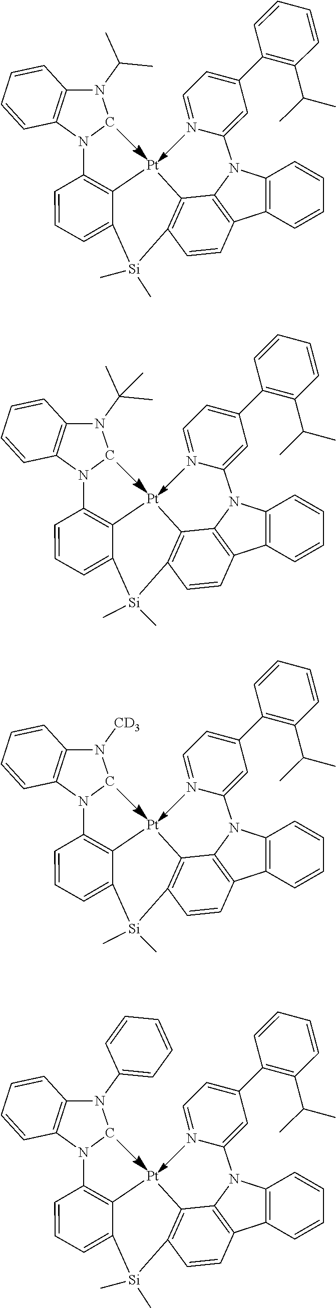

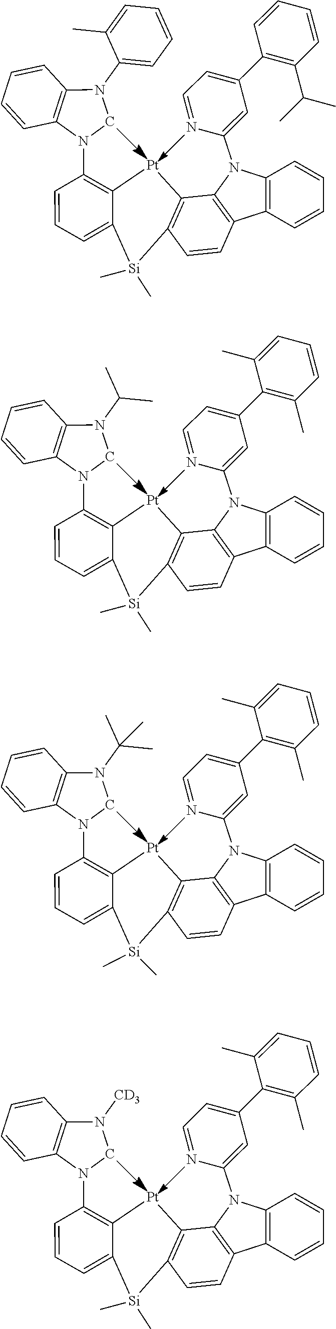

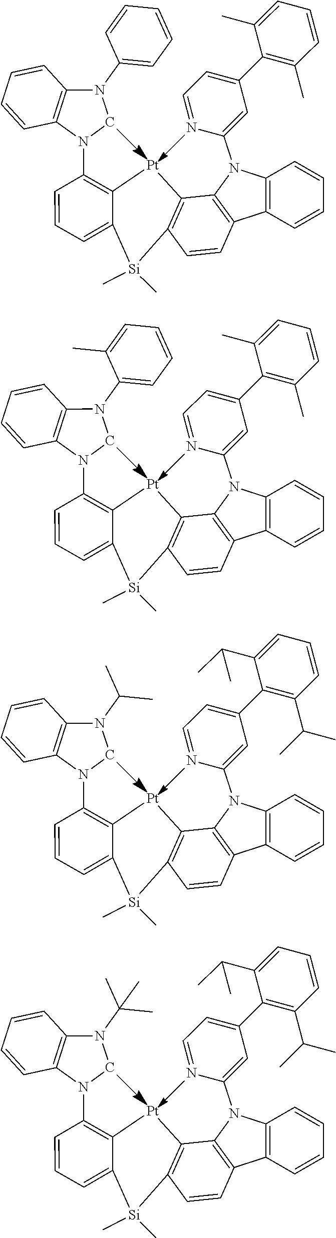

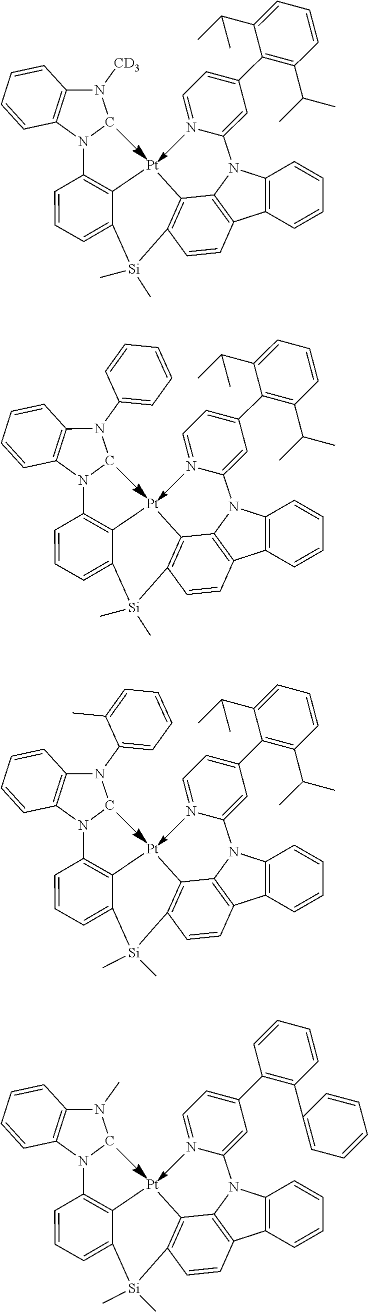

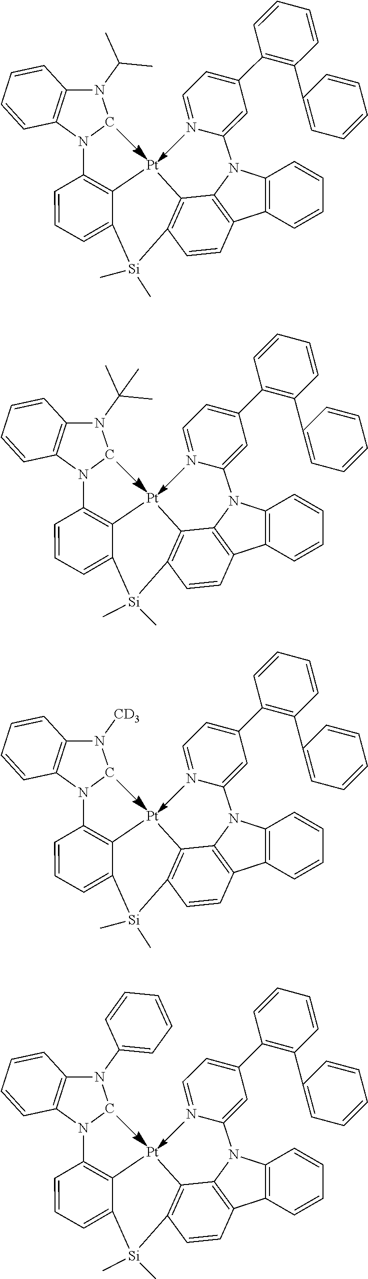

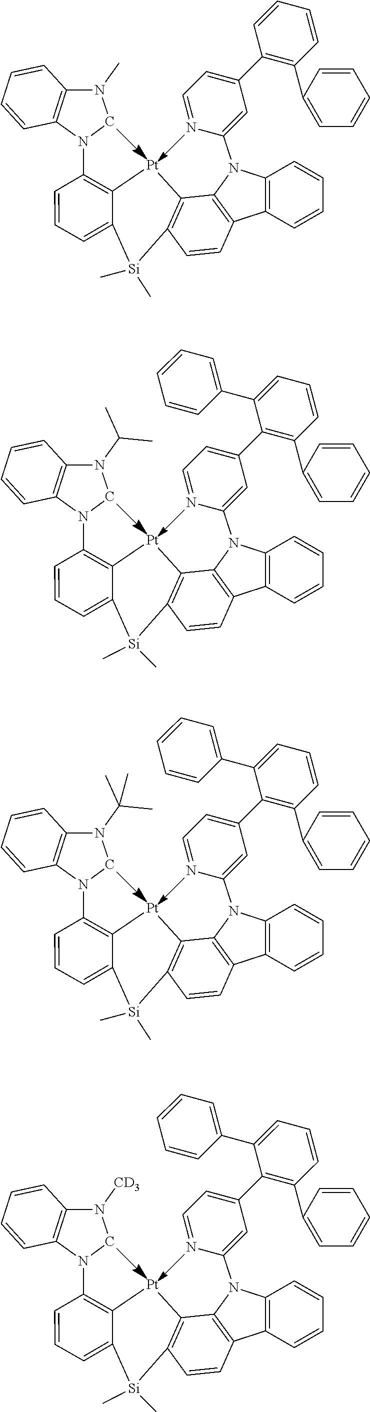

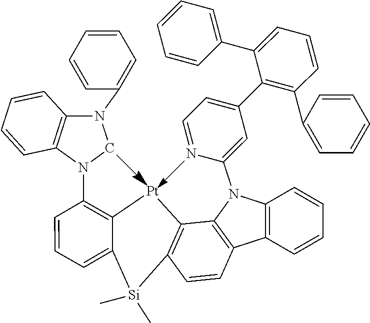

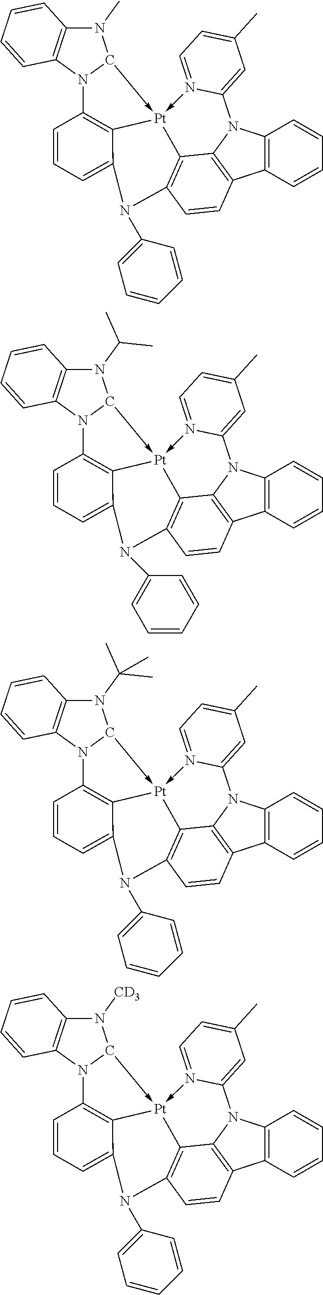

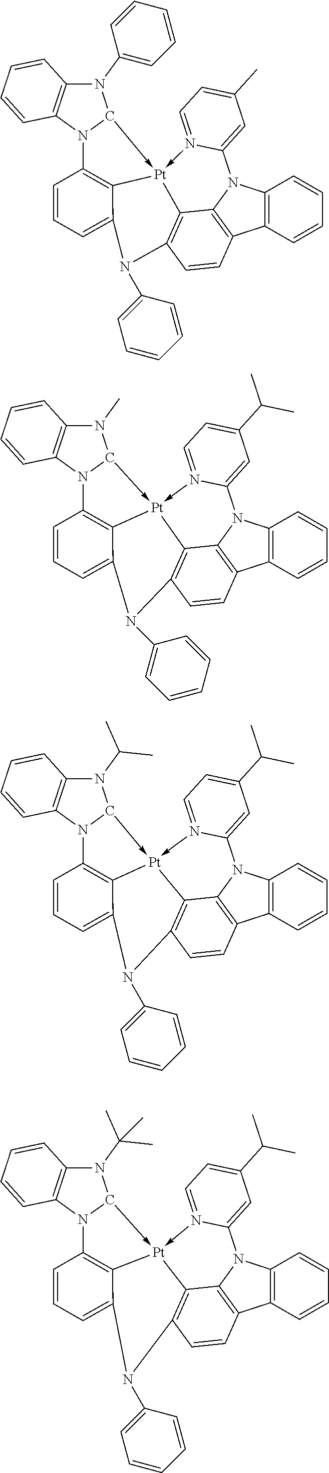

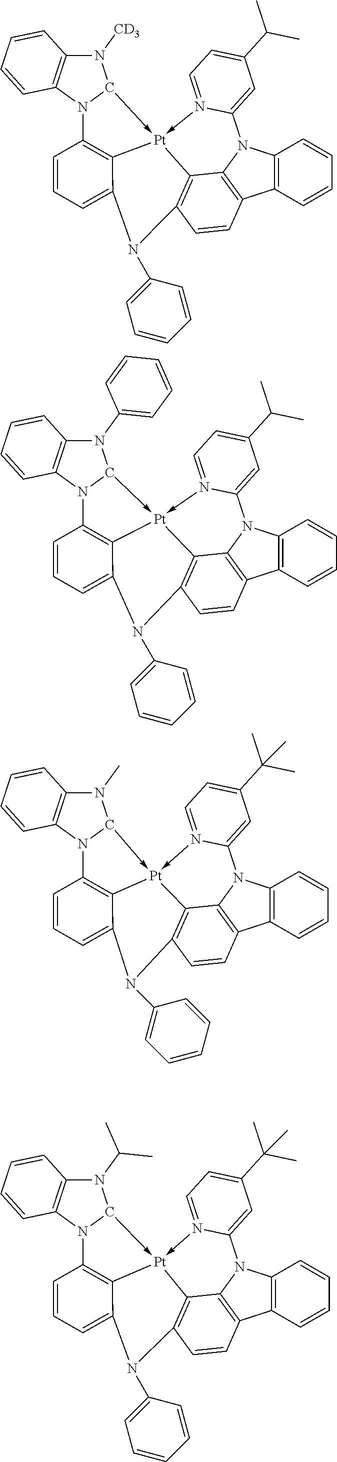

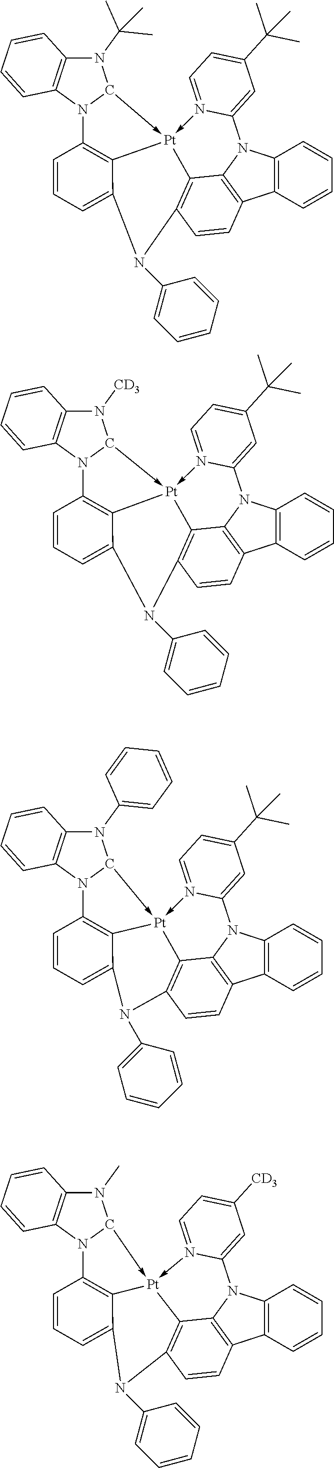

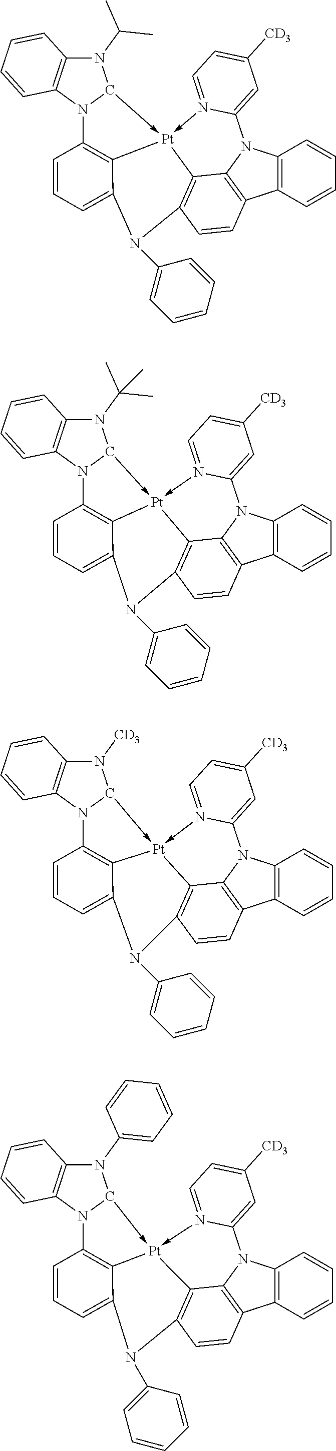

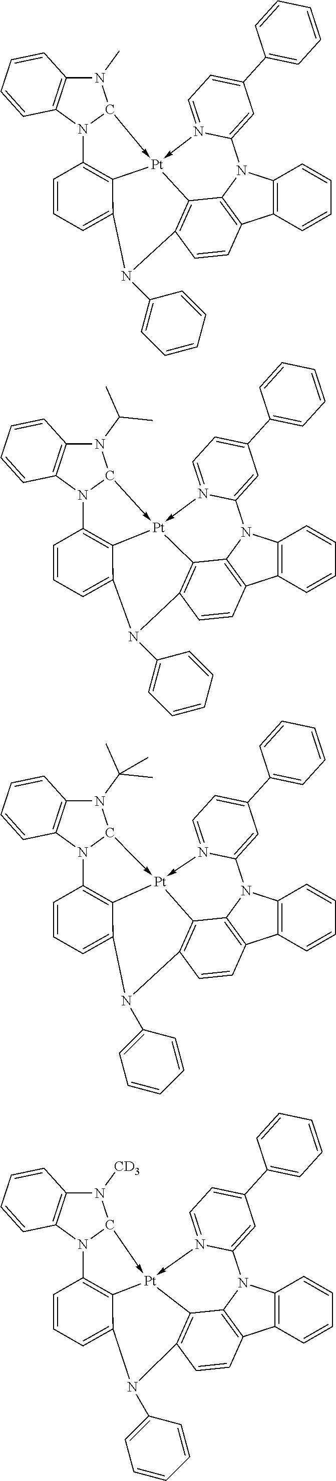

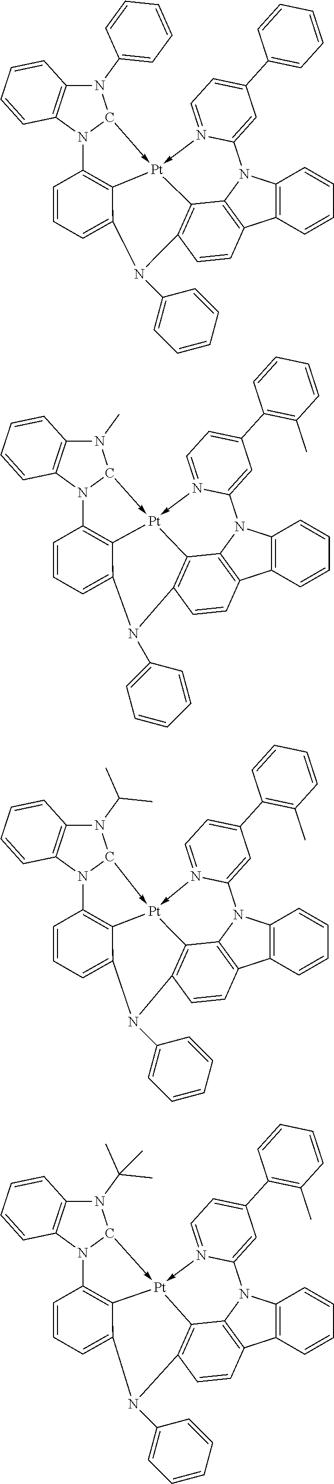

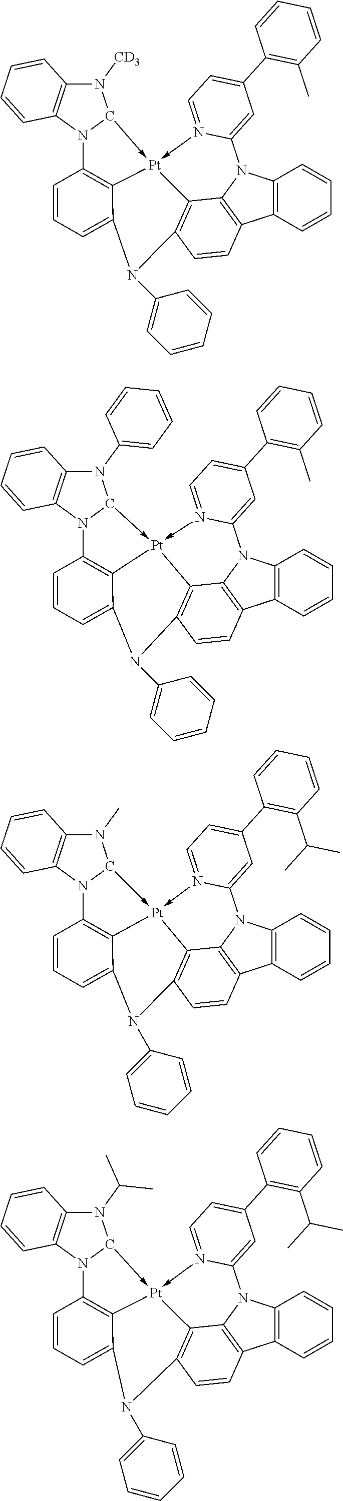

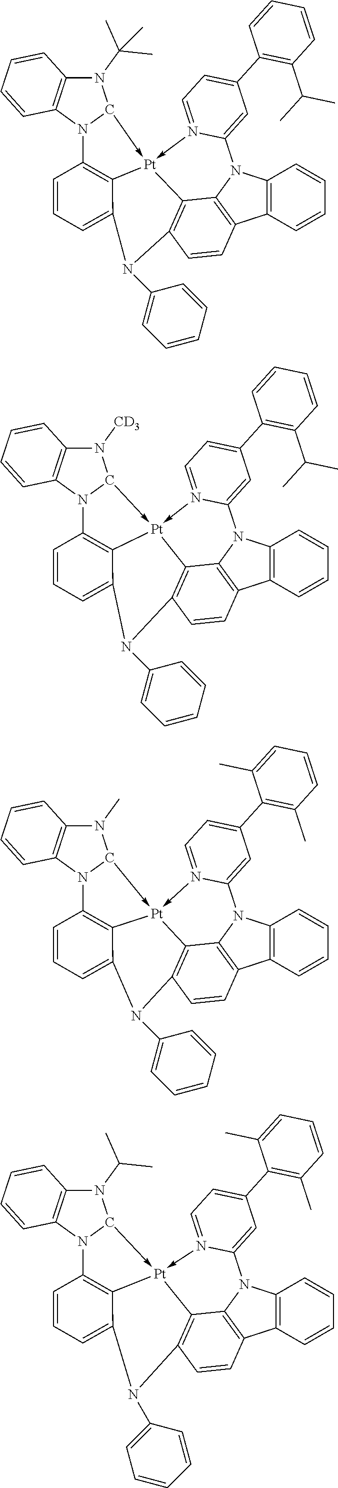

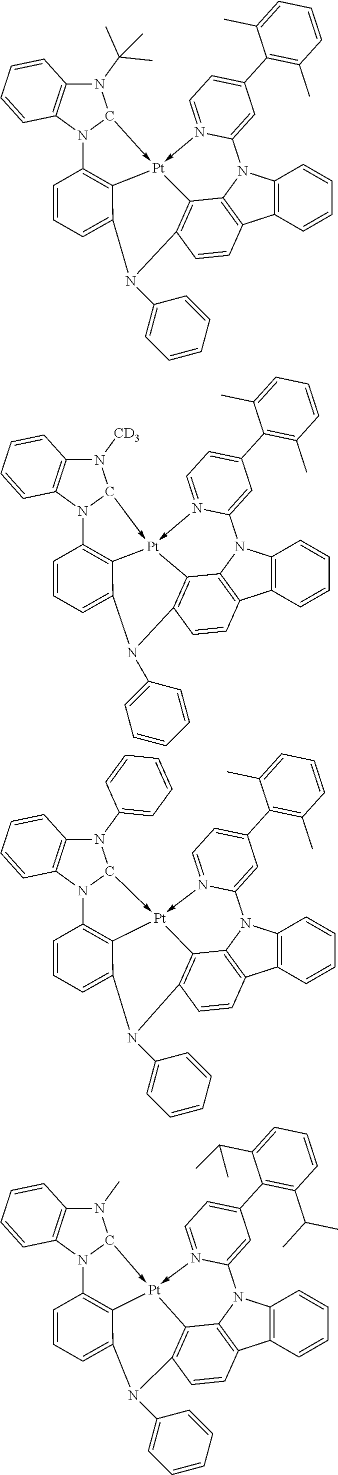

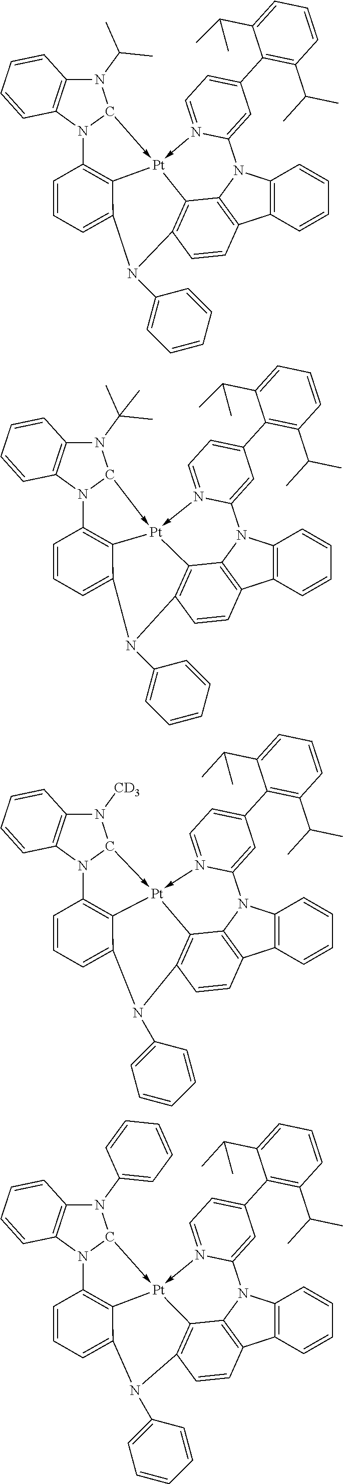

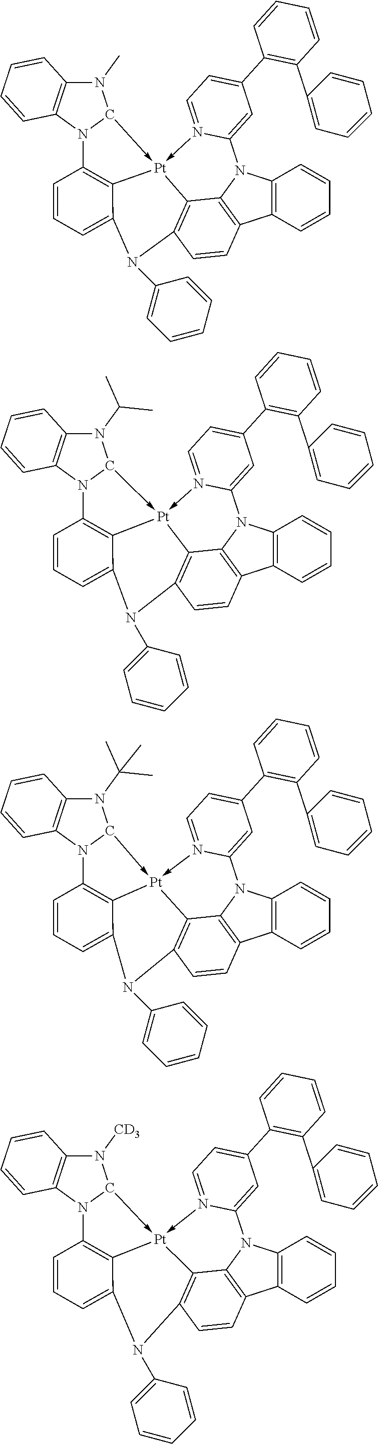

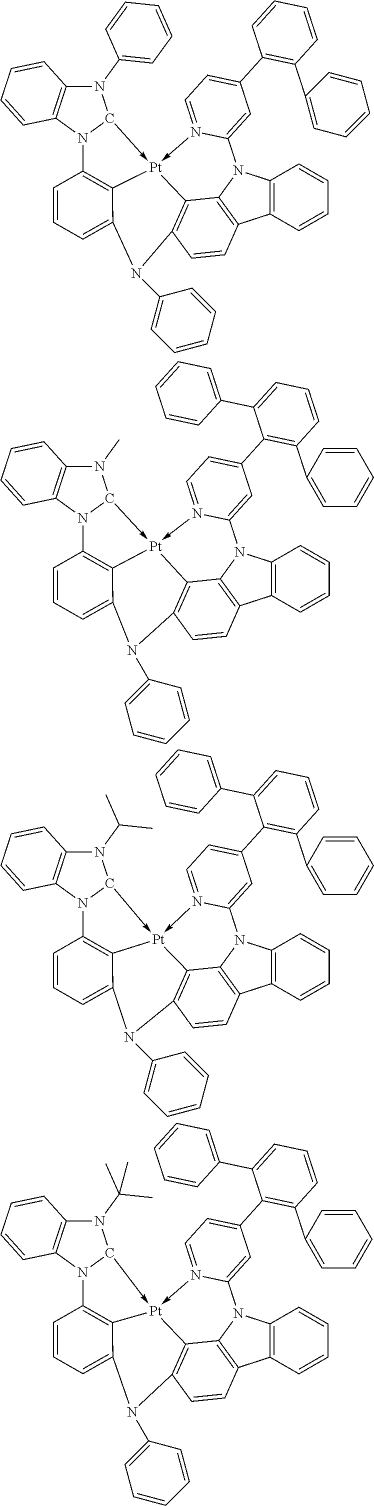

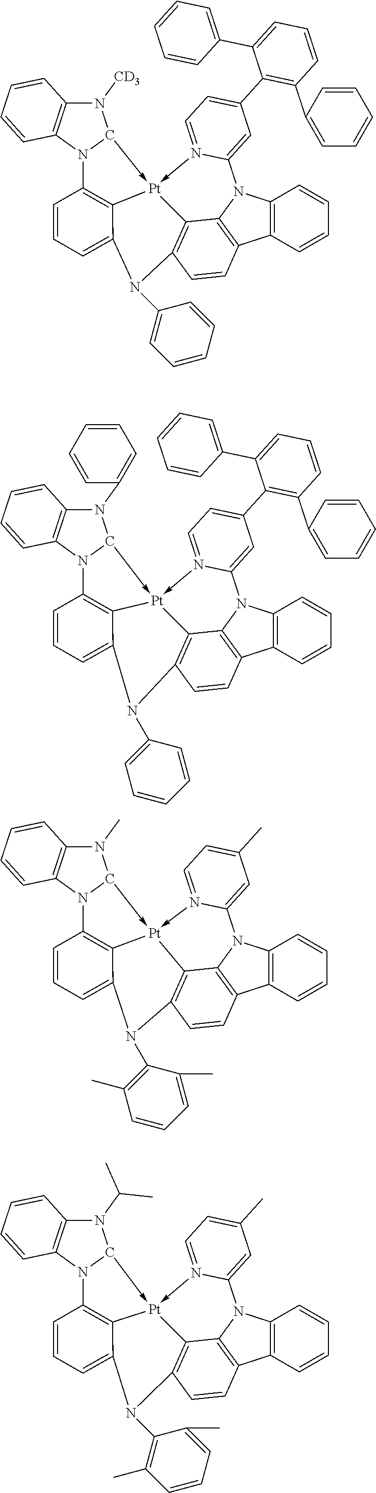

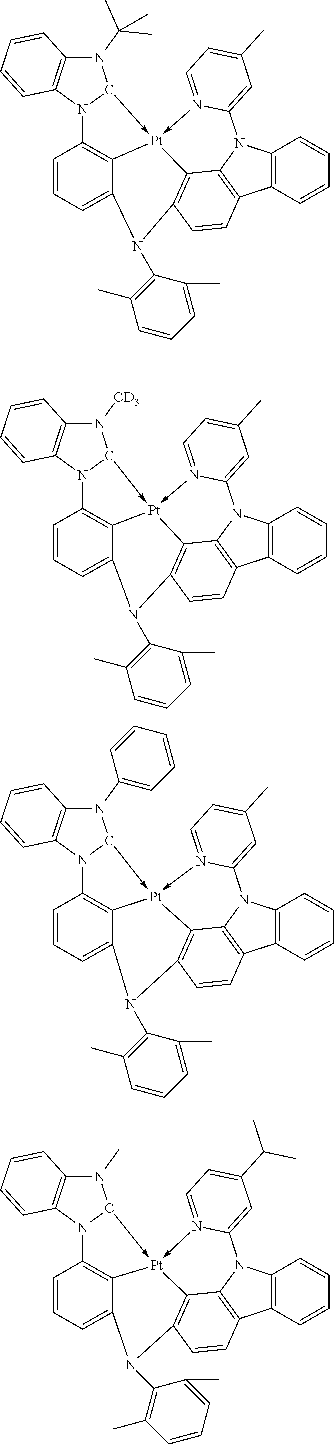

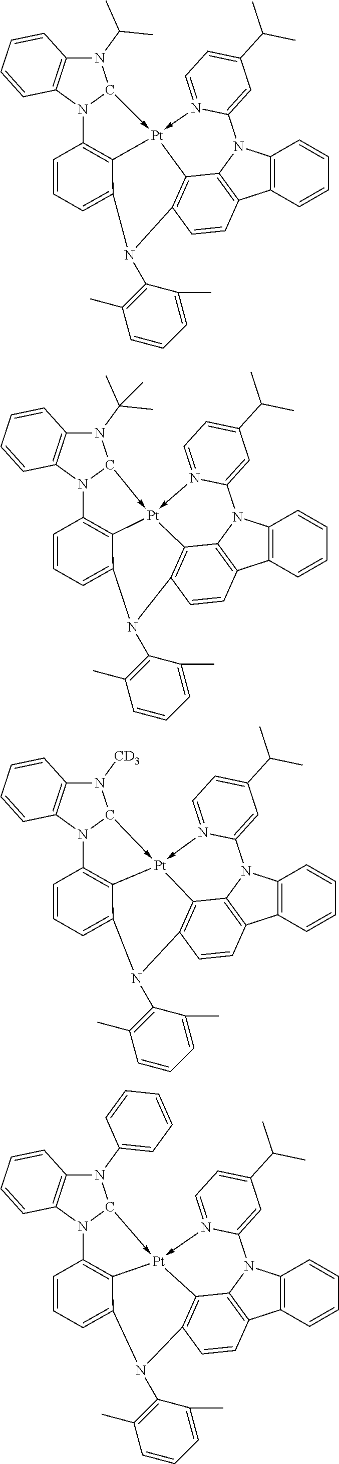

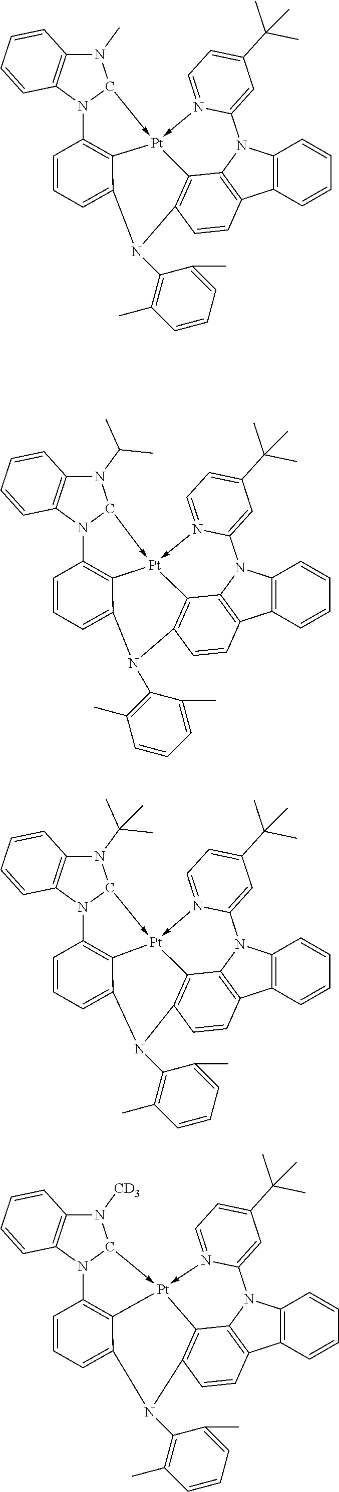

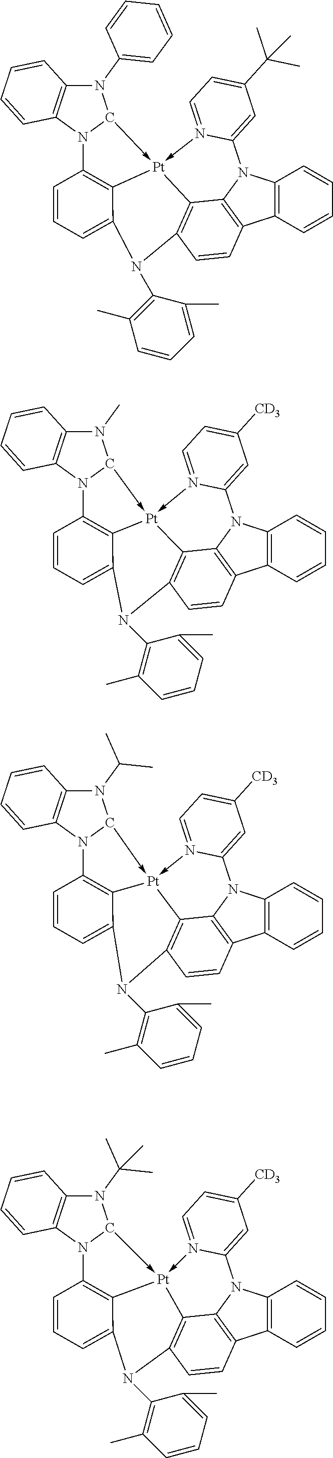

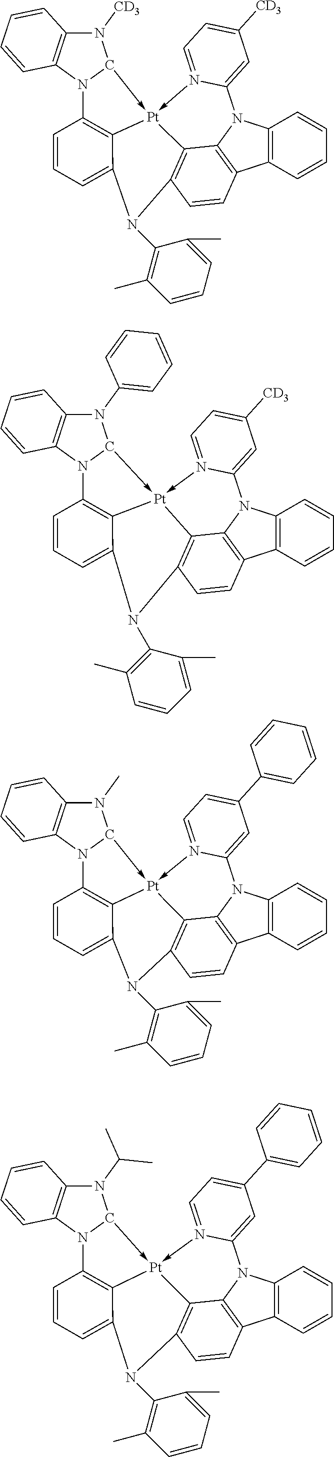

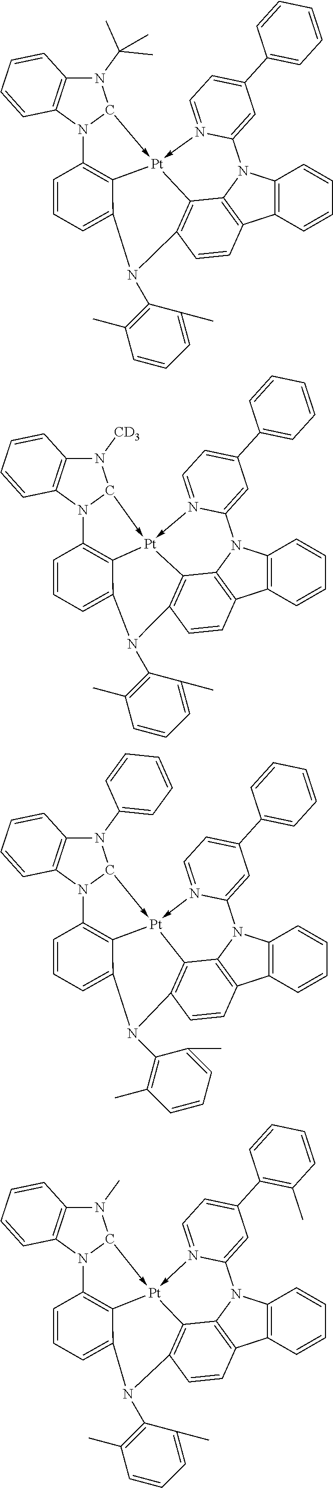

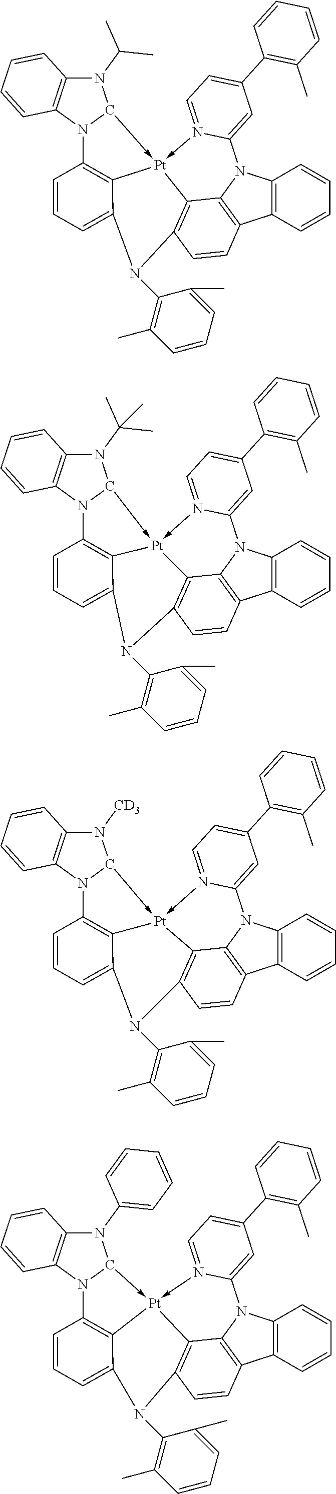

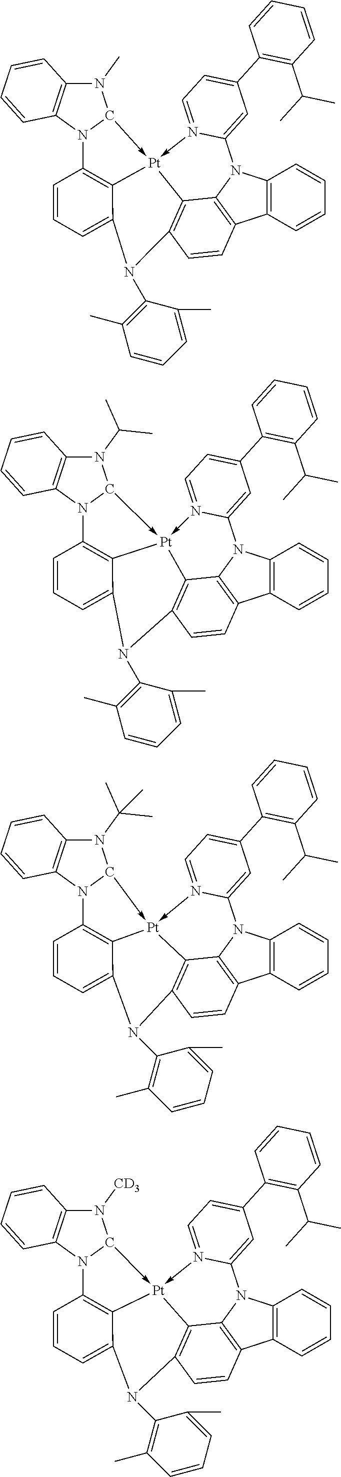

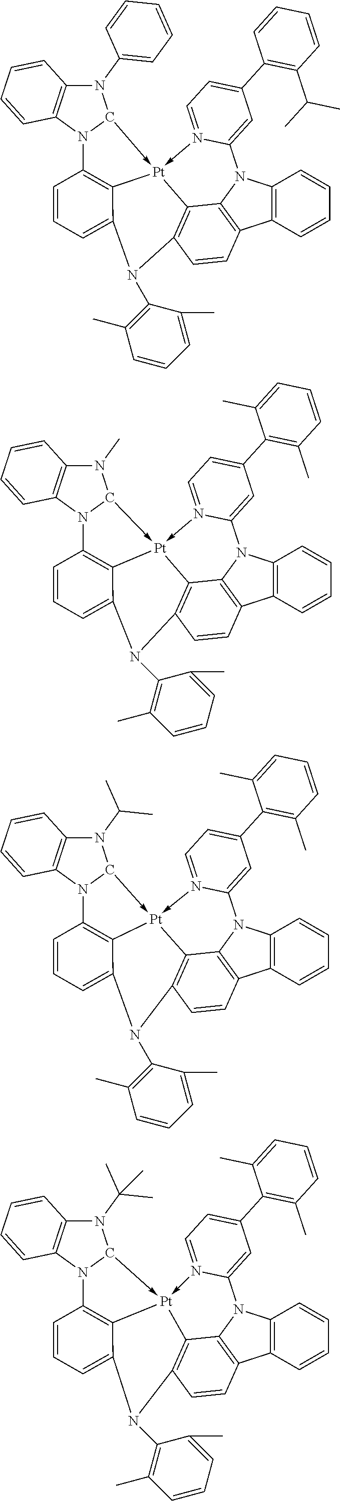

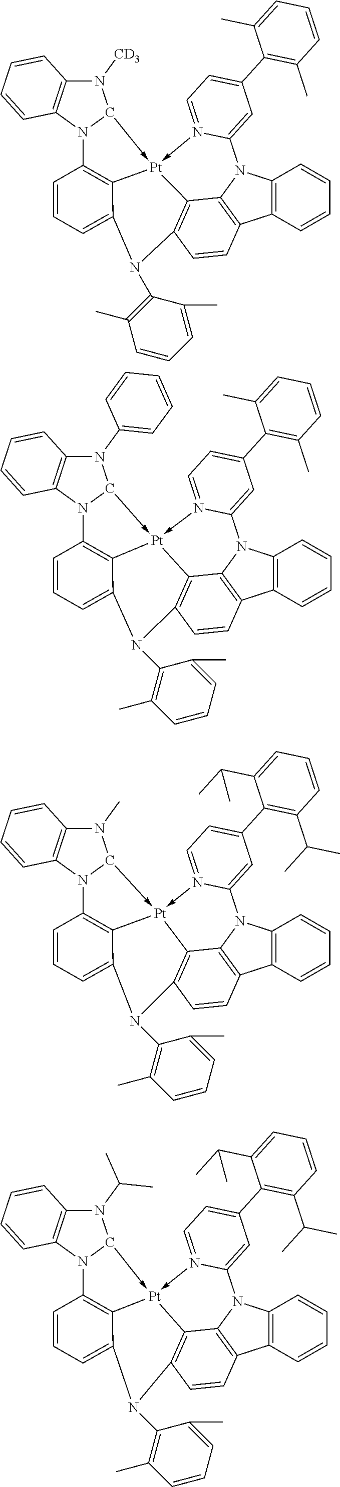

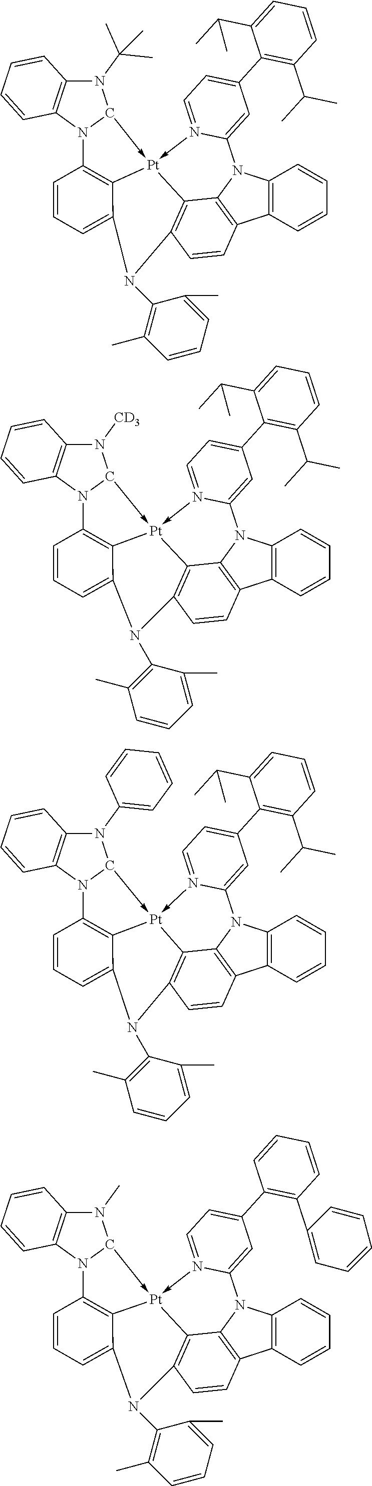

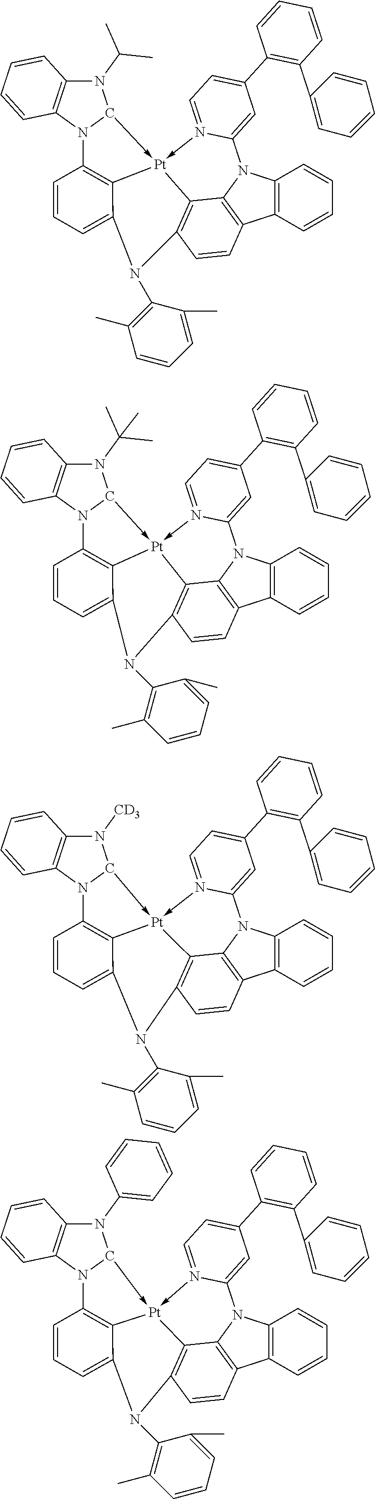

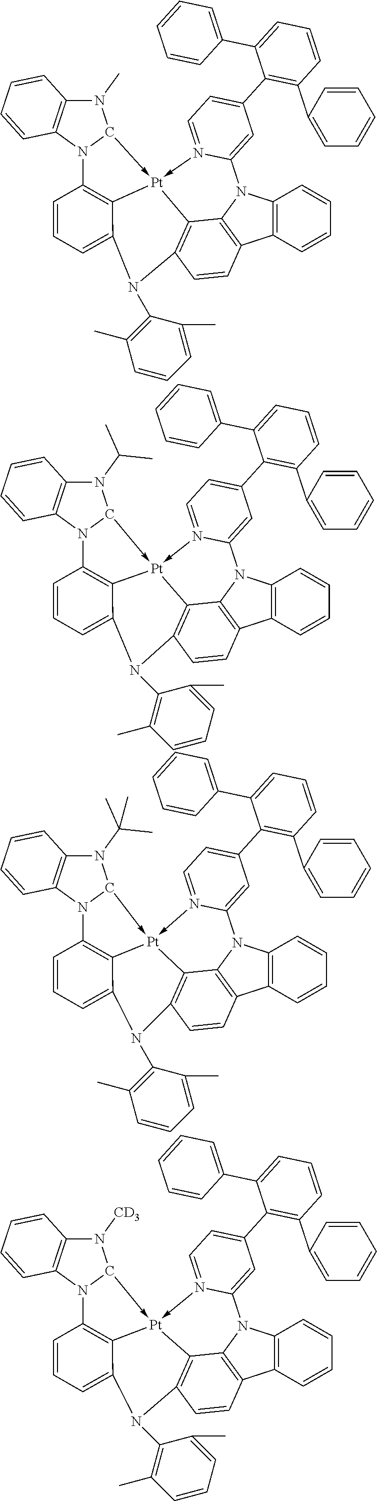

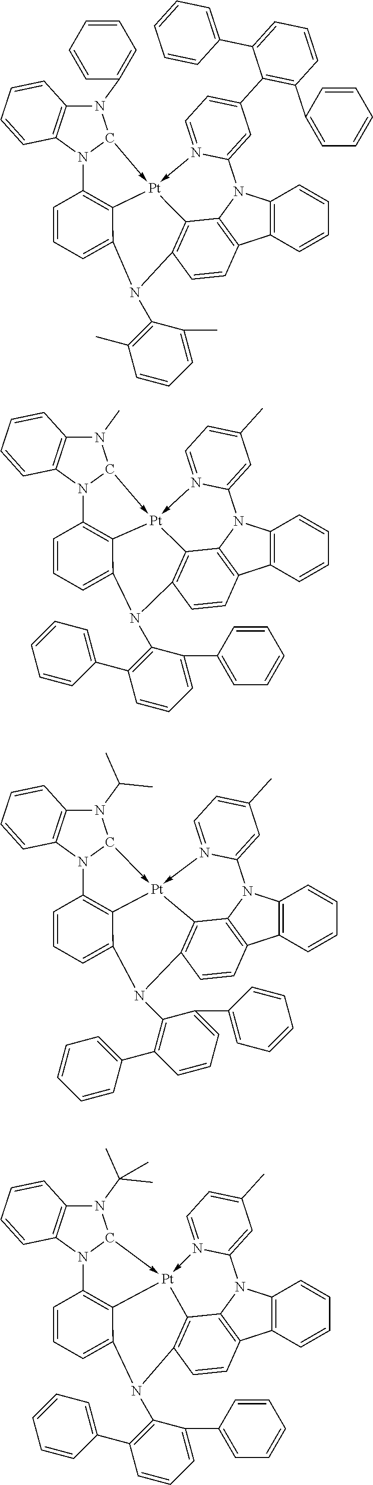

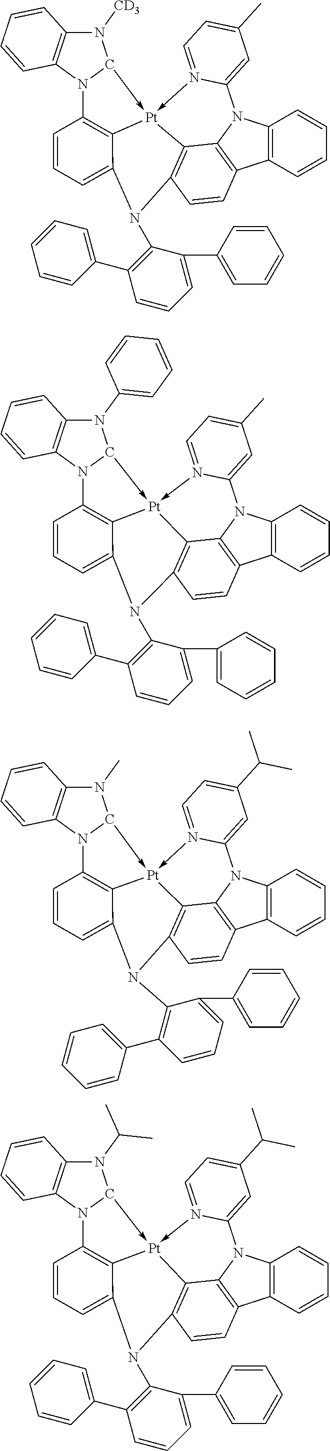

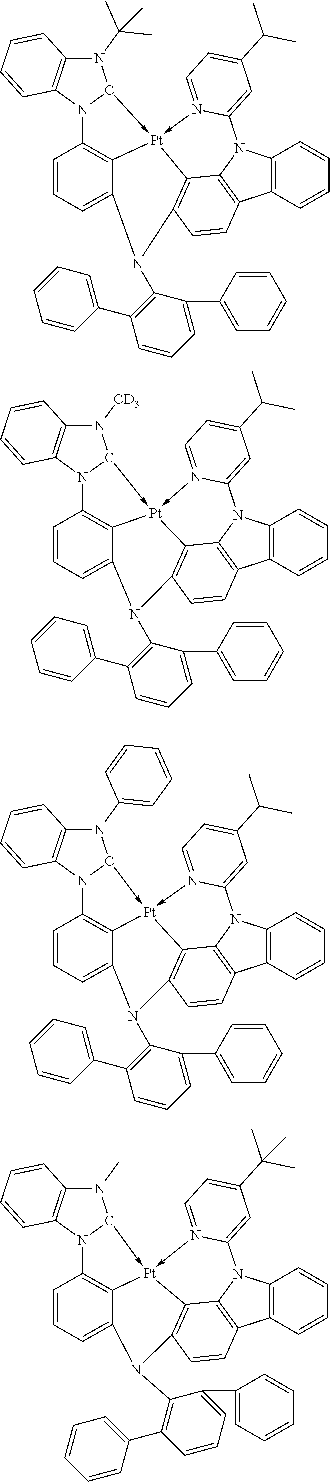

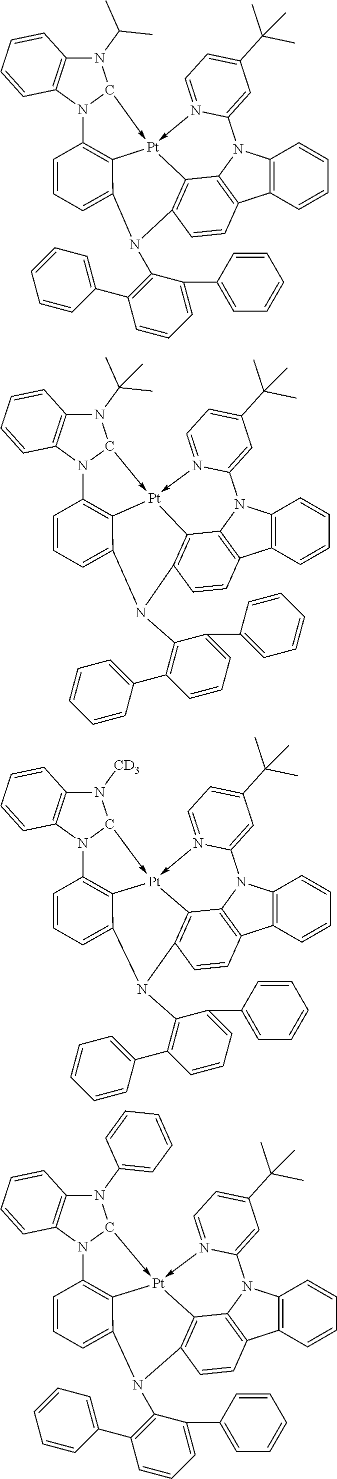

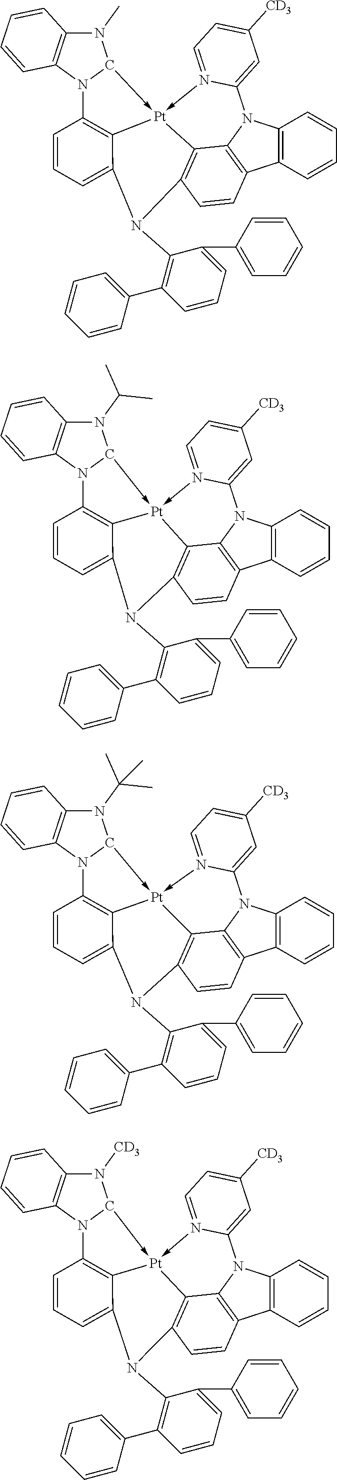

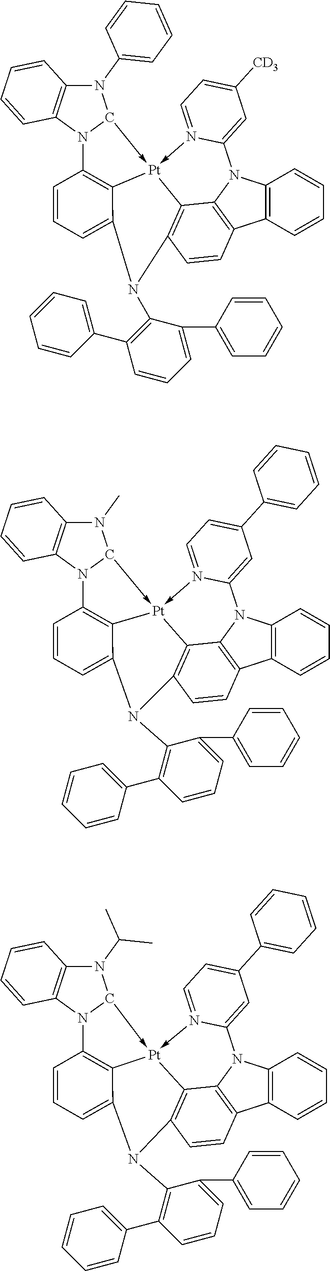

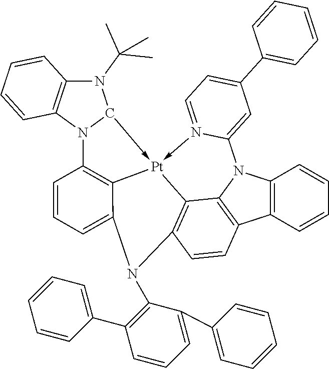

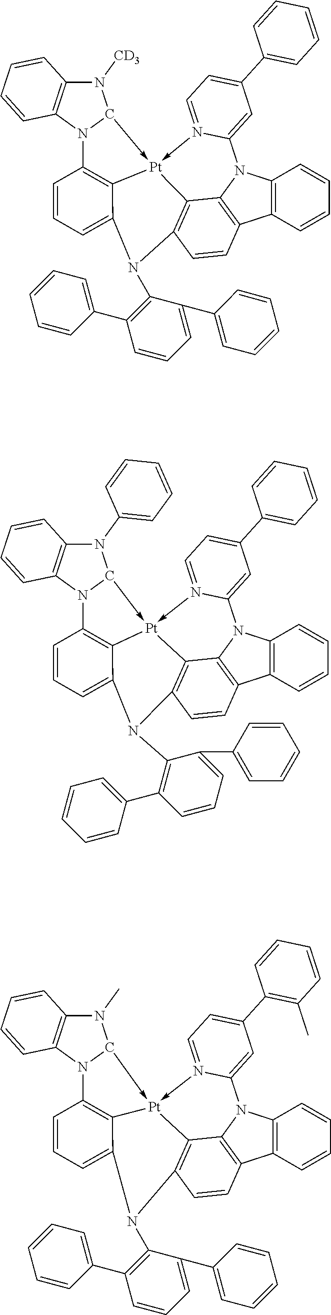

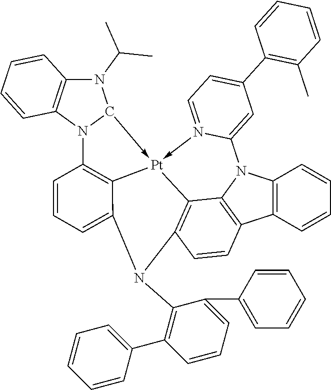

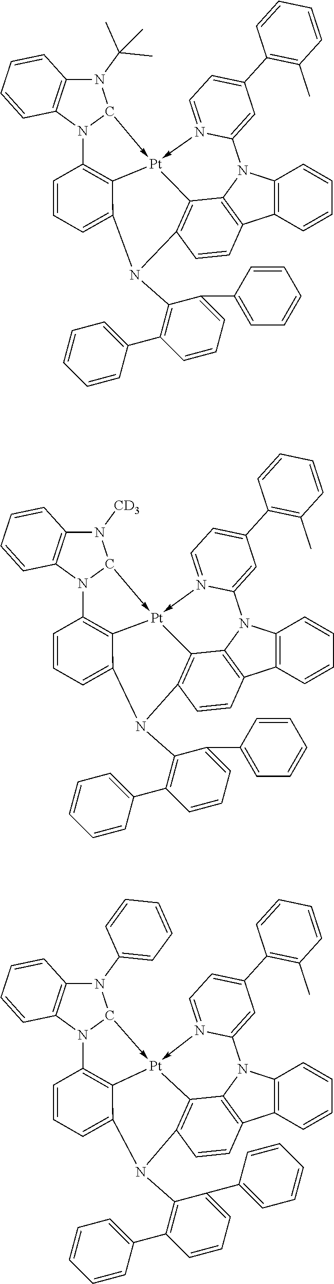

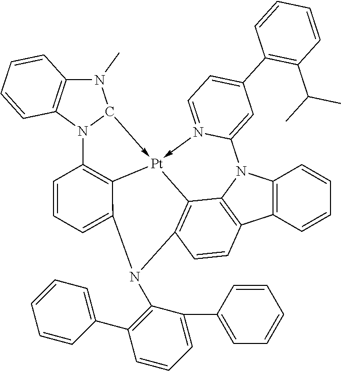

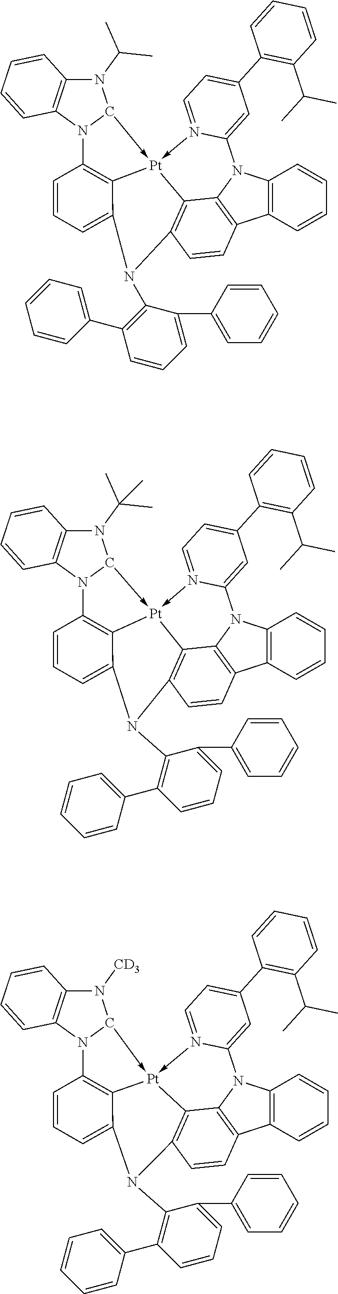

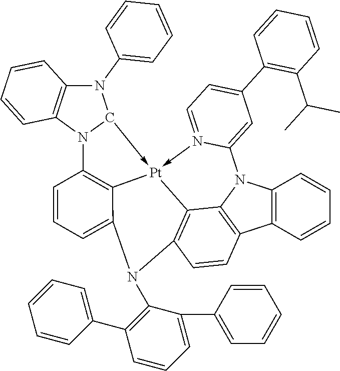

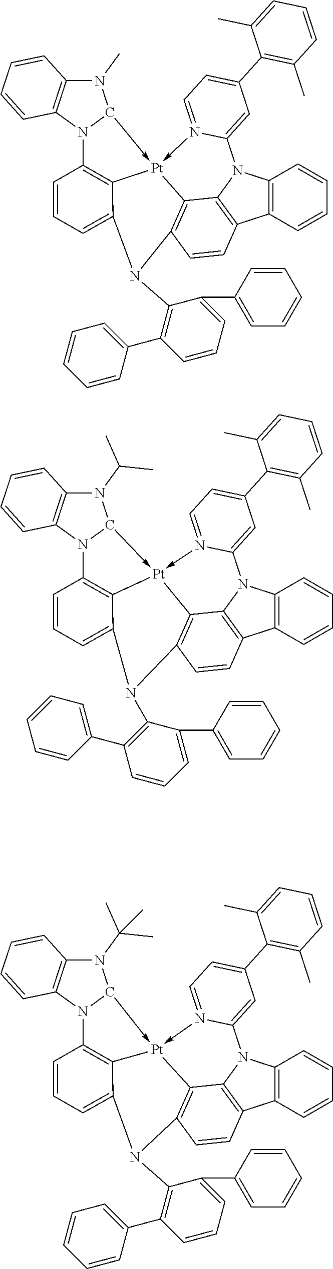

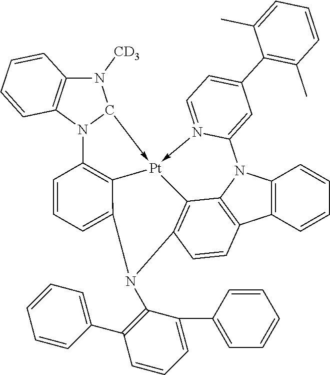

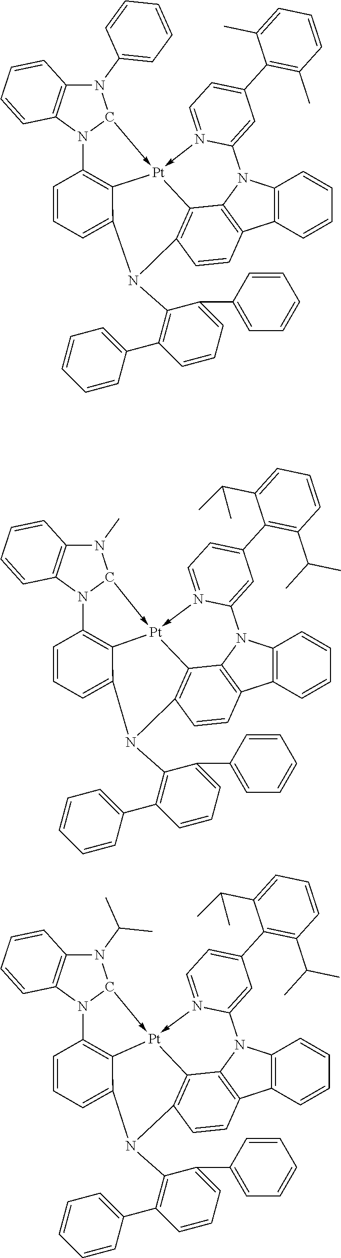

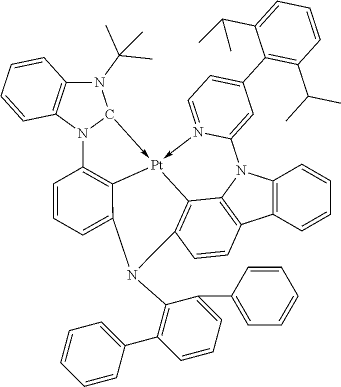

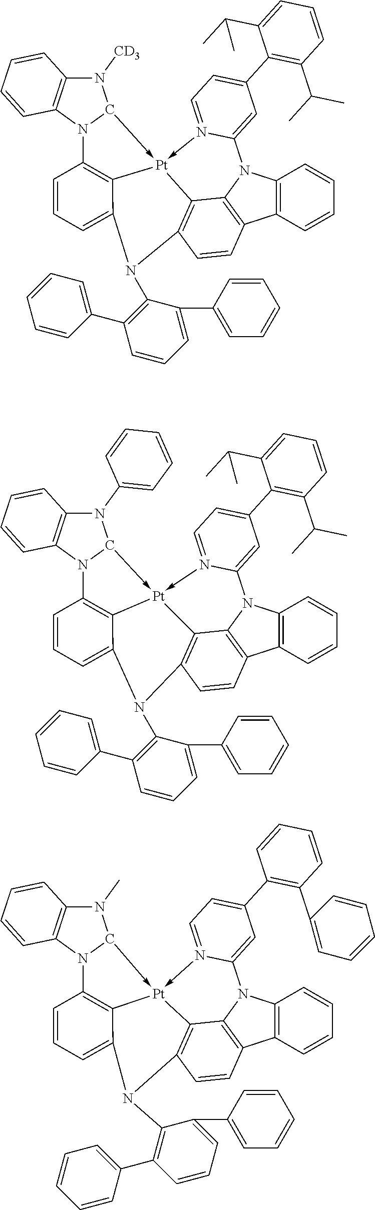

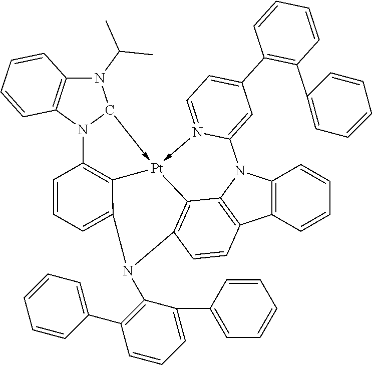

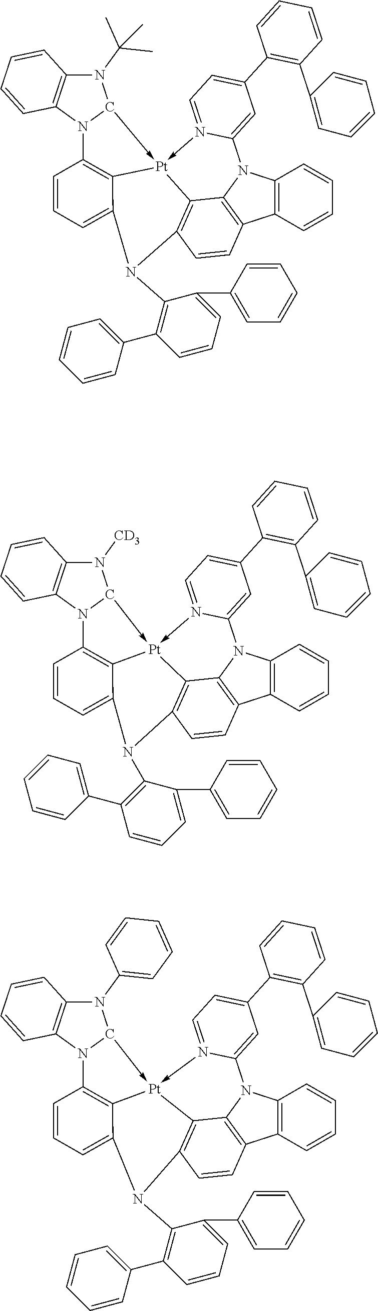

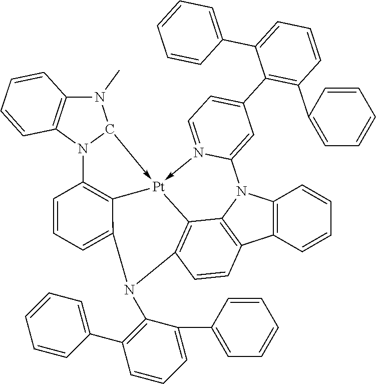

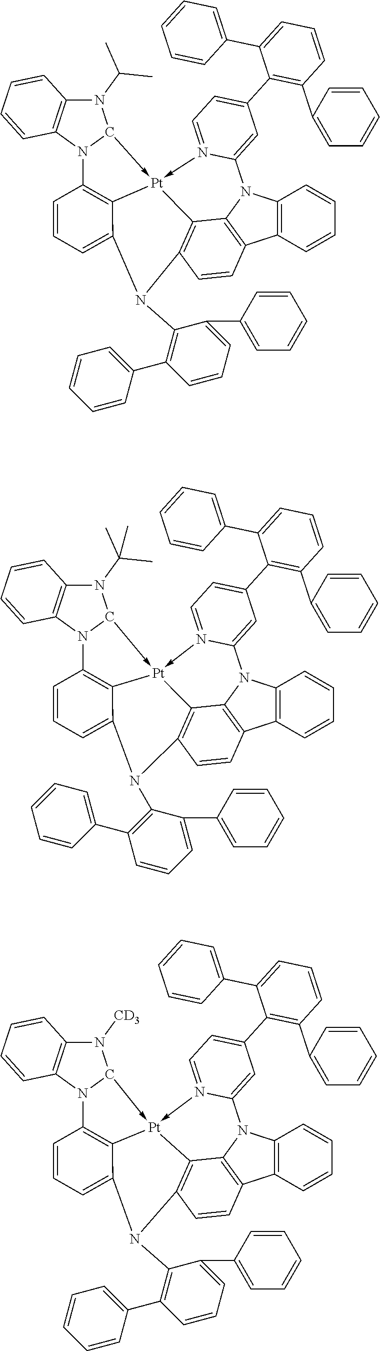

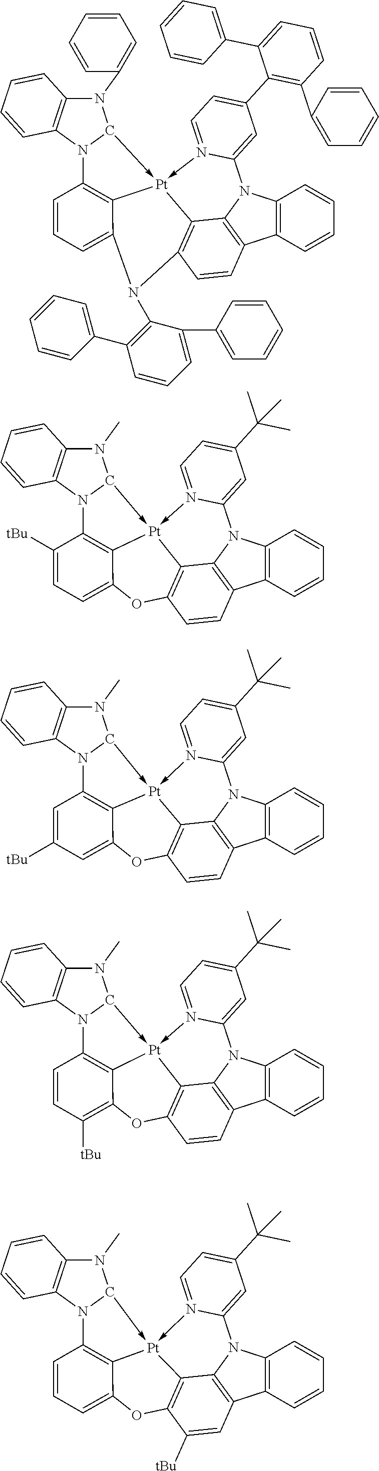

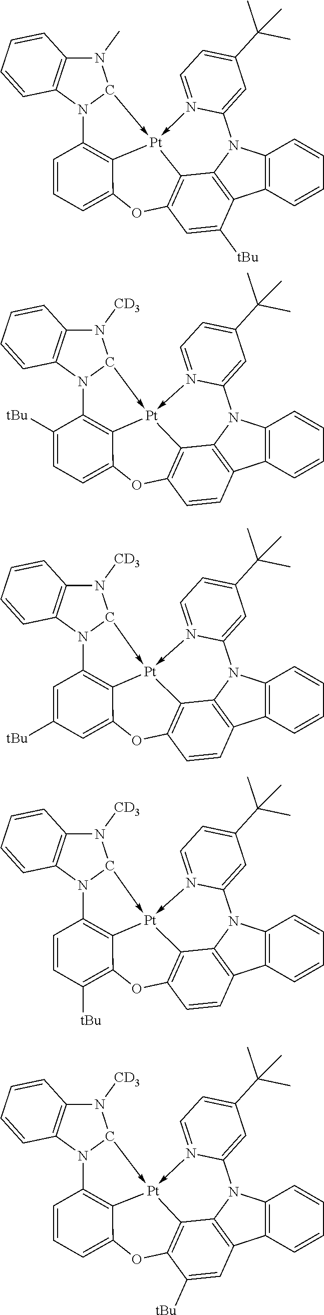

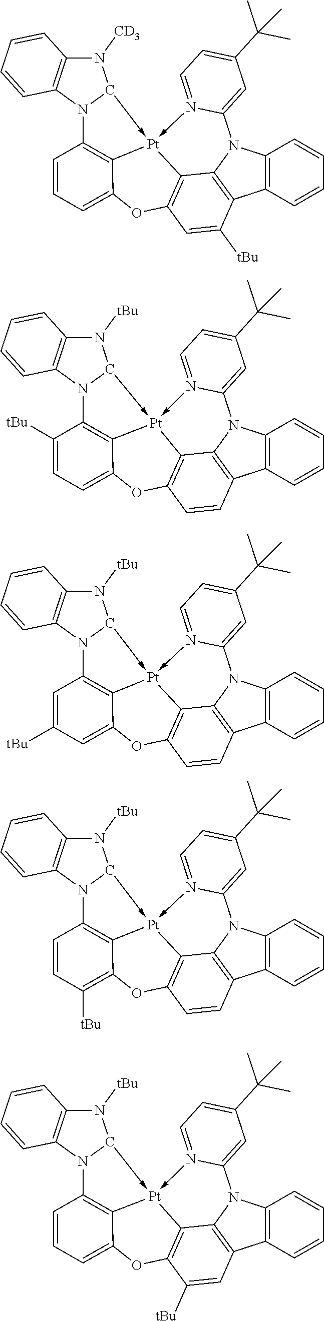

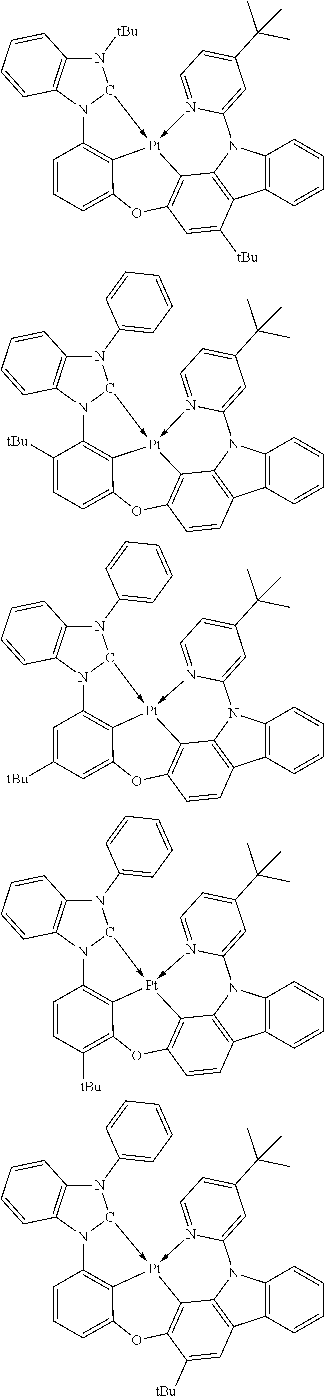

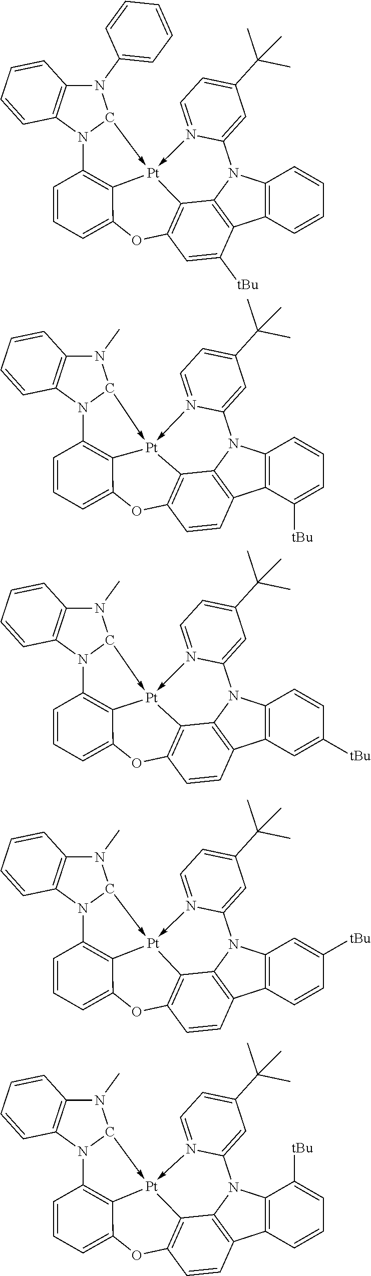

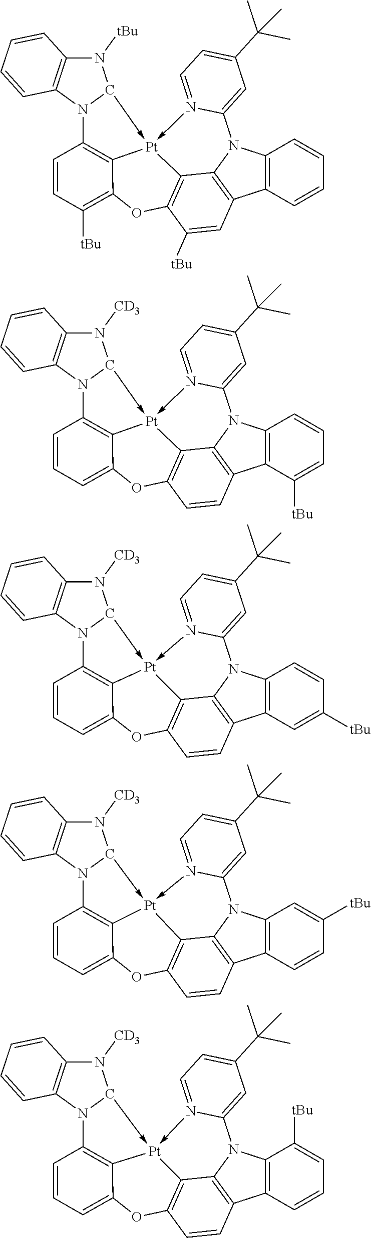

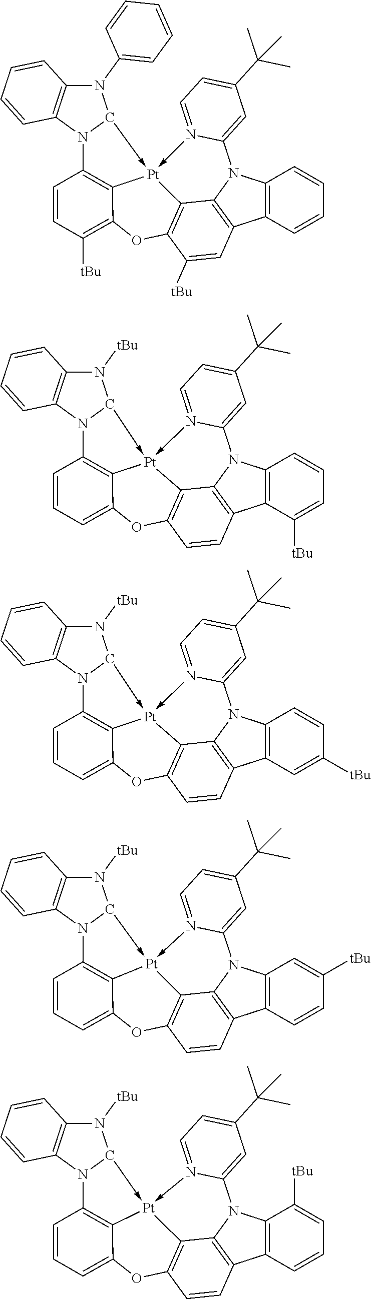

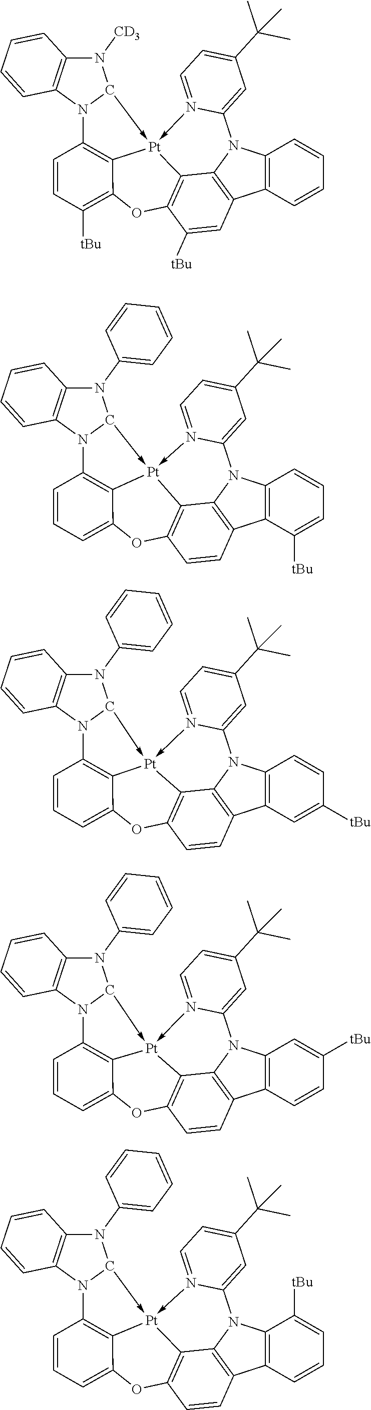

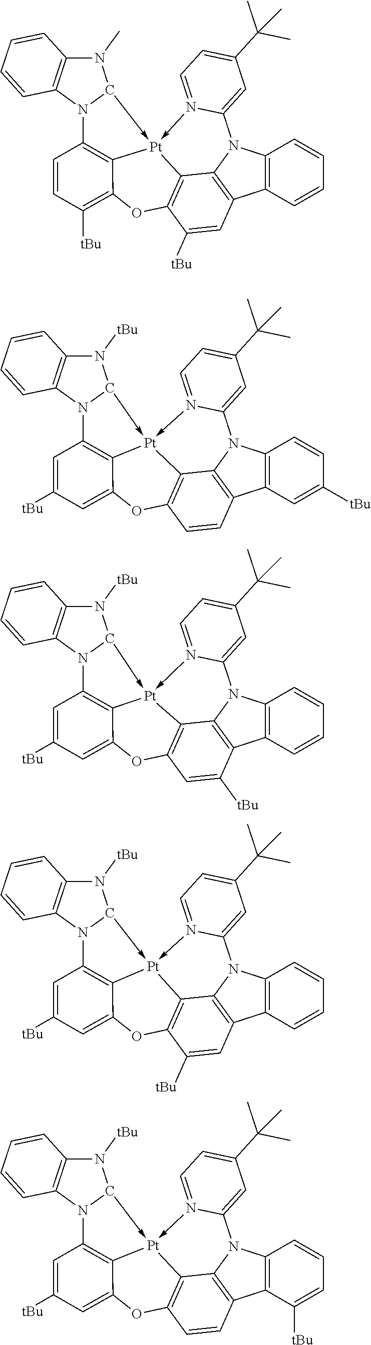

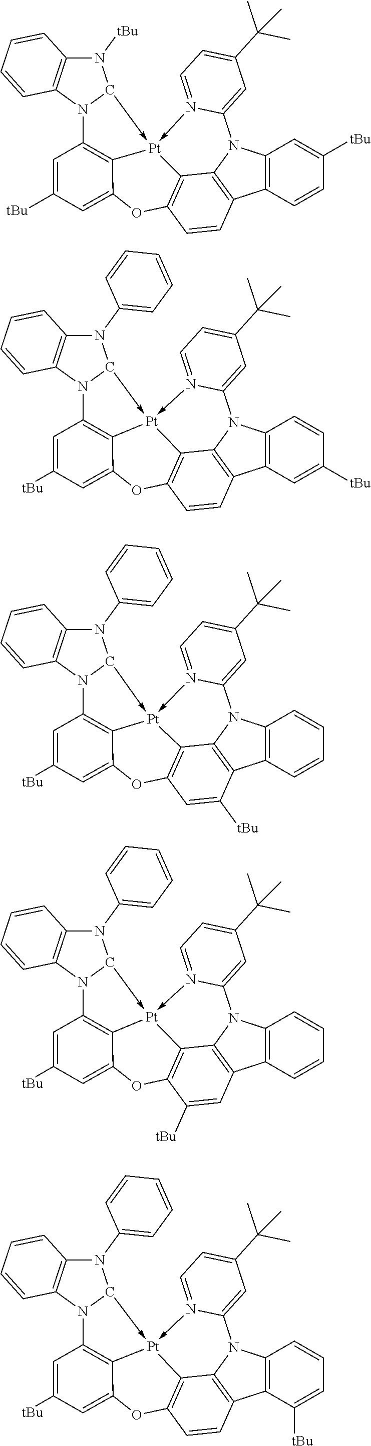

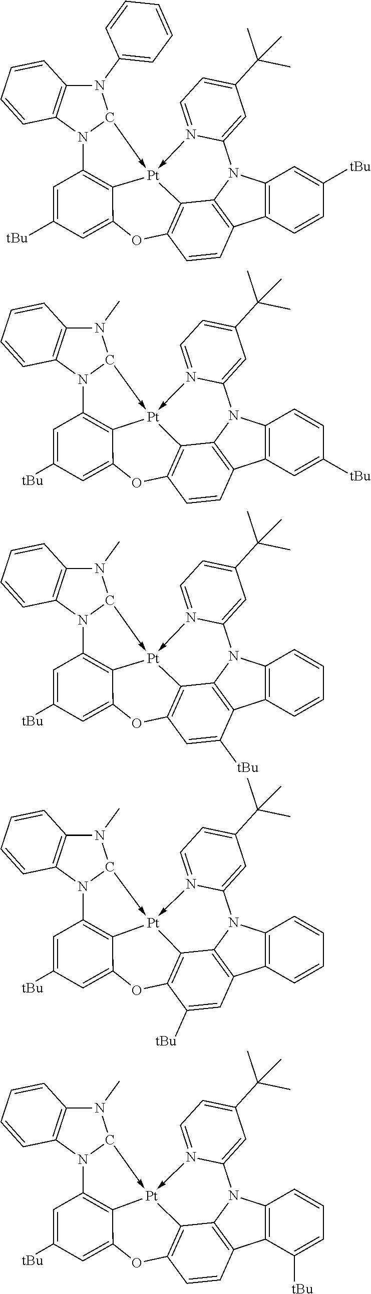

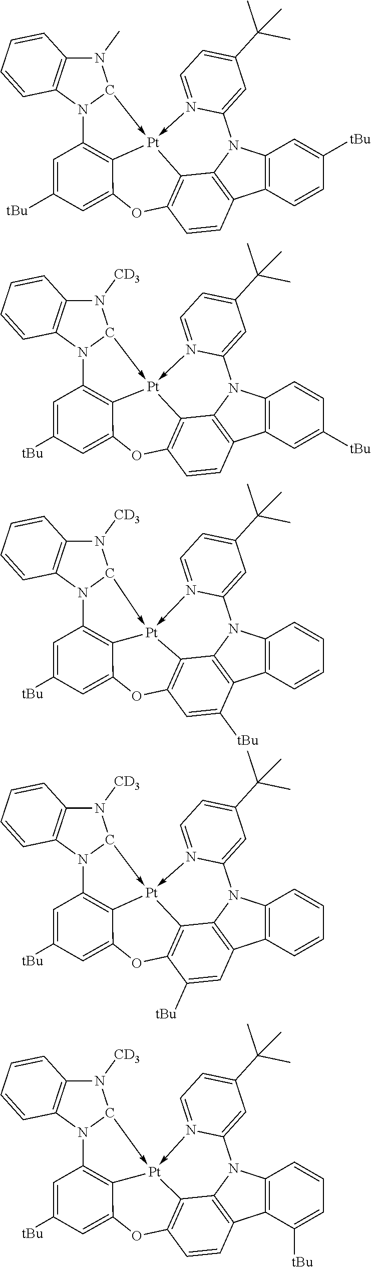

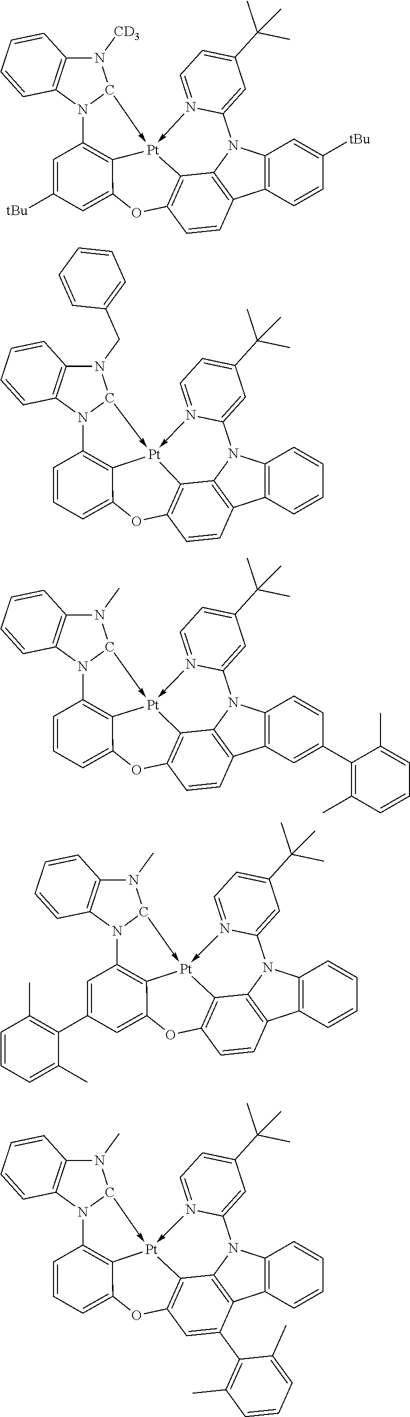

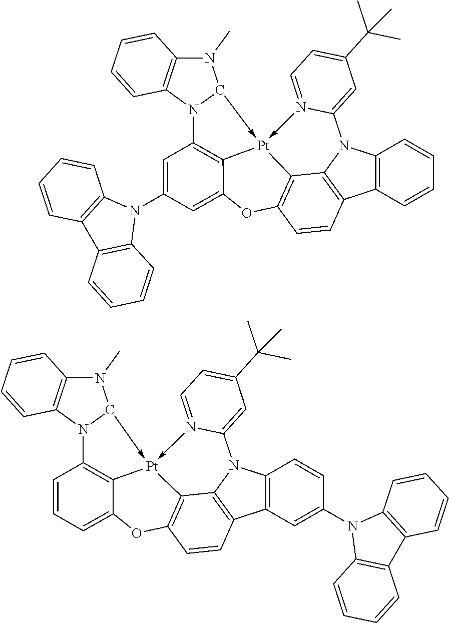

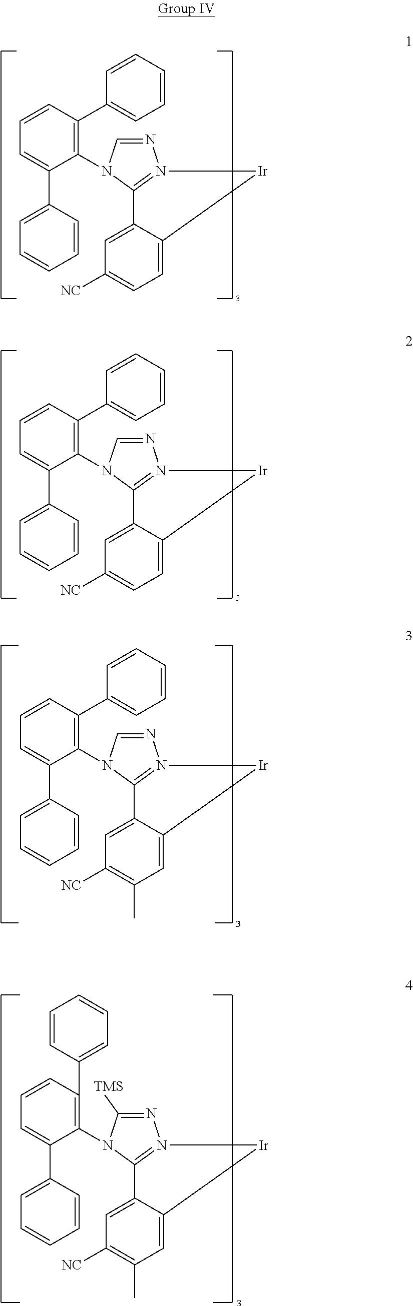

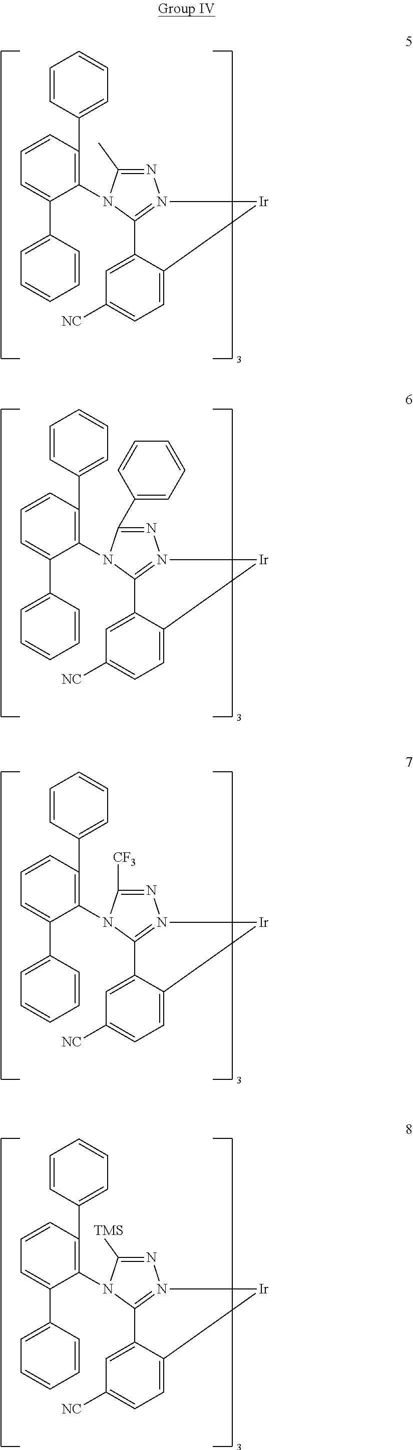

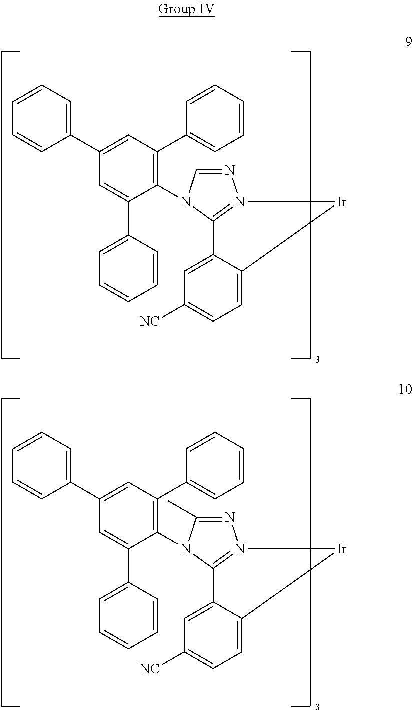

a compound represented by Formula A below:

(L₁₀₁)ₙ₁₀₁-M₁₀₁-(L₁₀₂)ₘ₁₀₁ Formula A

wherein, L₁₀₁, n101, M₁₀₁, L₁₀₂, and m101 in Formula A are as described in Tables 2 to 4 below:

TABLE 2

| Compound | L₁₀₁ | n101 | M₁₀₁ | L₁₀₂ | m101 |
|---|---|---|---|---|---|
| BD001 | LM1 | 3 | Ir | — | 0 |
| BD002 | LM2 | 3 | Ir | — | 0 |
| BD003 | LM3 | 3 | Ir | — | 0 |
| BD004 | LM4 | 3 | Ir | — | 0 |
| BD005 | LM5 | 3 | Ir | — | 0 |
| BD006 | LM6 | 3 | Ir | — | 0 |
| BD007 | LM7 | 3 | Ir | — | 0 |
| BD008 | LM8 | 3 | Ir | — | 0 |
| BD009 | LM9 | 3 | Ir | — | 0 |
| BD010 | LM10 | 3 | Ir | — | 0 |
| BD011 | LM11 | 3 | Ir | — | 0 |
| BD012 | LM12 | 3 | Ir | — | 0 |
| BD013 | LM13 | 3 | Ir | — | 0 |
| BD014 | LM14 | 3 | Ir | — | 0 |
| BD015 | LM15 | 3 | Ir | — | 0 |
| BD016 | LM16 | 3 | Ir | — | 0 |
| BD017 | LM17 | 3 | Ir | — | 0 |
| BD018 | LM18 | 3 | Ir | — | 0 |
| BD019 | LM19 | 3 | Ir | — | 0 |
| BD020 | LM20 | 3 | Ir | — | 0 |
| BD021 | LM21 | 3 | Ir | — | 0 |
| BD022 | LM22 | 3 | Ir | — | 0 |
| BD023 | LM23 | 3 | Ir | — | 0 |
| BD024 | LM24 | 3 | Ir | — | 0 |
| BD025 | LM25 | 3 | Ir | — | 0 |
| BD026 | LM26 | 3 | Ir | — | 0 |
| BD027 | LM27 | 3 | Ir | — | 0 |
| BD028 | LM28 | 3 | Ir | — | 0 |
| BD029 | LM29 | 3 | Ir | — | 0 |
| BD030 | LM30 | 3 | Ir | — | 0 |
| BD031 | LM31 | 3 | Ir | — | 0 |
| BD032 | LM32 | 3 | Ir | — | 0 |
| BD033 | LM33 | 3 | Ir | — | 0 |
| BD034 | LM34 | 3 | Ir | — | 0 |
| BD035 | LM35 | 3 | Ir | — | 0 |
| BD036 | LM36 | 3 | Ir | — | 0 |
| BD037 | LM37 | 3 | Ir | — | 0 |
| BD038 | LM38 | 3 | Ir | — | 0 |
| BD039 | LM39 | 3 | Ir | — | 0 |
| BD040 | LM40 | 3 | Ir | — | 0 |
| BD041 | LM41 | 3 | Ir | — | 0 |
| BD042 | LM42 | 3 | Ir | — | 0 |
| BD043 | LM43 | 3 | Ir | — | 0 |
| BD044 | LM44 | 3 | Ir | — | 0 |
| BD045 | LM45 | 3 | Ir | — | 0 |
| BD046 | LM46 | 3 | Ir | — | 0 |
| BD047 | LM47 | 3 | Ir | — | 0 |
| BD048 | LM48 | 3 | Ir | — | 0 |
| BD049 | LM49 | 3 | Ir | — | 0 |
| BD050 | LM50 | 3 | Ir | — | 0 |
| BD051 | LM51 | 3 | Ir | — | 0 |
| BD052 | LM52 | 3 | Ir | — | 0 |
| BD053 | LM53 | 3 | Ir | — | 0 |
| BD054 | LM54 | 3 | Ir | — | 0 |
| BD055 | LM55 | 3 | Ir | — | 0 |
| BD056 | LM56 | 3 | Ir | — | 0 |
| BD057 | LM57 | 3 | Ir | — | 0 |
| BD058 | LM58 | 3 | Ir | — | 0 |
| BD059 | LM59 | 3 | Ir | — | 0 |
| BD060 | LM60 | 3 | Ir | — | 0 |
| BD061 | LM61 | 3 | Ir | — | 0 |
| BD062 | LM62 | 3 | Ir | — | 0 |
| BD063 | LM63 | 3 | Ir | — | 0 |
| BD064 | LM64 | 3 | Ir | — | 0 |
| BD065 | LM65 | 3 | Ir | — | 0 |
| BD066 | LM66 | 3 | Ir | — | 0 |
| BD067 | LM67 | 3 | Ir | — | 0 |
| BD068 | LM68 | 3 | Ir | — | 0 |
| BD069 | LM69 | 3 | Ir | — | 0 |
| BD070 | LM70 | 3 | Ir | — | 0 |
| BD071 | LM71 | 3 | Ir | — | 0 |
| BD072 | LM72 | 3 | Ir | — | 9 |
| BD073 | LM73 | 3 | Ir | — | 0 |
| BD074 | LM74 | 3 | Ir | — | 0 |
| BD075 | LM75 | 3 | Ir | — | 0 |
| BD076 | LM76 | 3 | Ir | — | 0 |
| BD077 | LM77 | 3 | Ir | — | 0 |
| BD078 | LM78 | 3 | Ir | — | 0 |
| BD079 | LM79 | 3 | Ir | — | 0 |
| BD080 | LM80 | 3 | Ir | — | 0 |
| BD081 | LM81 | 3 | Ir | — | 0 |
| BD082 | LM82 | 3 | Ir | — | 0 |
| BD083 | LM83 | 3 | Ir | — | 0 |
| BD084 | LM84 | 3 | Ir | — | 0 |
| BD085 | LM85 | 3 | Ir | — | 0 |
| BD086 | LM86 | 3 | Ir | — | 0 |
| BD087 | LM87 | 3 | Ir | — | 0 |
| BD088 | LM88 | 3 | Ir | — | 0 |
| BD089 | LM89 | 3 | Ir | — | 0 |
| BD090 | LM90 | 3 | Ir | — | 0 |
| BD091 | LM91 | 3 | Ir | — | 0 |
| BD092 | LM92 | 3 | Ir | — | 0 |
| BD093 | LM93 | 3 | Ir | — | 0 |
| BD094 | LM94 | 3 | Ir | — | 0 |
| BD095 | LM95 | 3 | Ir | — | 0 |
| BD096 | LM96 | 3 | Ir | — | 0 |
| BD097 | LM97 | 3 | Ir | — | 0 |
| BD093 | LM98 | 3 | Ir | — | 0 |
| BD099 | LM99 | 3 | Ir | — | 0 |
| BD100 | LM100 | 3 | Ir | — | 0 |

TABLE 3

| Compound | L₁₀₁ | n101 | M₁₀₁ | L₁₀₂ | m101 |
|---|---|---|---|---|---|
| BD101 | LM101 | 3 | Ir | — | 0 |
| BD102 | LM102 | 3 | Ir | — | 0 |
| BD103 | LM103 | 3 | Ir | — | 0 |
| BD104 | LM104 | 3 | Ir | — | 0 |
| BD105 | LM105 | 3 | Ir | — | 0 |
| BD106 | LM106 | 3 | Ir | — | 0 |
| BD107 | LM107 | 3 | Ir | — | 0 |
| BD108 | LM108 | 3 | Ir | — | 0 |
| BD109 | LM109 | 3 | Ir | — | 0 |
| BD110 | LM110 | 3 | Ir | — | 0 |
| BD111 | LM111 | 3 | Ir | — | 0 |
| BD112 | LM112 | 3 | Ir | — | 0 |
| BD113 | LM113 | 3 | Ir | — | 0 |
| BD114 | LM114 | 3 | Ir | — | 0 |
| BD115 | LM115 | 3 | Ir | — | 0 |
| BD116 | LM116 | 3 | Ir | — | 0 |
| BD117 | LM117 | 3 | Ir | — | 0 |
| BD118 | LM118 | 3 | Ir | — | 0 |
| BD119 | LM119 | 3 | Ir | — | 0 |
| BD120 | LM120 | 3 | Ir | — | 0 |
| BD121 | LM121 | 3 | Ir | — | 0 |
| BD122 | LM122 | 3 | Ir | — | 0 |
| BD123 | LM123 | 3 | Ir | — | 0 |
| BD124 | LM124 | 3 | Ir | — | 0 |
| BD125 | LM125 | 3 | Ir | — | 0 |
| BD126 | LM126 | 3 | Ir | — | 0 |
| BD127 | LM127 | 3 | Ir | — | 0 |
| BD128 | LM128 | 3 | Ir | — | 0 |
| BD129 | LM129 | 3 | Ir | — | 0 |
| BD130 | LM130 | 3 | Ir | — | 0 |
| BD131 | LM131 | 3 | Ir | — | 0 |
| BD132 | LM132 | 3 | Ir | — | 0 |
| BD133 | LM133 | 3 | Ir | — | 0 |
| BD134 | LM134 | 3 | Ir | — | 0 |
| BD135 | LM135 | 3 | Ir | — | 0 |
| BD136 | LM136 | 3 | Ir | — | 0 |
| BD137 | LM137 | 3 | Ir | — | 0 |
| BD138 | LM138 | 3 | Ir | — | 0 |
| BD139 | LM139 | 3 | Ir | — | 0 |
| BD140 | LM140 | 3 | Ir | — | 0 |
| BD141 | LM141 | 3 | Ir | — | 0 |
| BD142 | LM142 | 3 | Ir | — | 0 |
| BD143 | LM143 | 3 | Ir | — | 0 |
| BD144 | LM144 | 3 | Ir | — | 0 |
| BD145 | LM145 | 3 | Ir | — | 0 |
| BD146 | LM146 | 3 | Ir | — | 0 |
| BD147 | LM147 | 3 | Ir | — | 0 |
| BD148 | LM148 | 3 | Ir | — | 0 |
| BD149 | LM149 | 3 | Ir | — | 0 |
| BD150 | LM150 | 3 | Ir | — | 0 |
| BD151 | LM151 | 3 | Ir | — | 0 |
| BD152 | LM152 | 3 | Ir | — | 0 |
| BD153 | LM153 | 3 | Ir | — | 0 |
| BD154 | LM154 | 3 | Ir | — | 0 |
| BD155 | LM155 | 3 | Ir | — | 0 |
| BD156 | LM156 | 3 | Ir | — | 0 |
| BD157 | LM157 | 3 | Ir | — | 0 |
| BD158 | LM158 | 3 | Ir | — | 0 |
| BD159 | LM159 | 3 | Ir | — | 0 |
| BD160 | LM160 | 3 | Ir | — | 0 |
| BD161 | LM161 | 3 | Ir | — | 0 |
| BD162 | LM162 | 3 | Ir | — | 0 |
| BD163 | LM163 | 3 | Ir | — | 0 |
| BD164 | LM164 | 3 | Ir | — | 0 |
| BD165 | LM165 | 3 | Ir | — | 0 |
| BD166 | LM166 | 3 | Ir | — | 0 |
| BD167 | LM167 | 3 | Ir | — | 0 |
| BD168 | LM168 | 3 | Ir | — | 0 |
| BD169 | LM169 | 3 | Ir | — | 0 |
| BD170 | LM170 | 3 | Ir | — | 0 |
| BD171 | LM171 | 3 | Ir | — | 0 |
| BD172 | LM172 | 3 | Ir | — | 0 |
| BD173 | LM173 | 3 | Ir | — | 0 |
| BD174 | LM174 | 3 | Ir | — | 0 |
| BD175 | LM175 | 3 | Ir | — | 0 |
| BD176 | LM176 | 3 | Ir | — | 0 |
| BD177 | LM177 | 3 | Ir | — | 0 |
| BD178 | LM178 | 3 | Ir | — | 0 |
| BD179 | LM179 | 3 | Ir | — | 0 |
| BD180 | LM180 | 3 | Ir | — | 0 |
| BD181 | LM181 | 3 | Ir | — | 0 |
| BD182 | LM182 | 3 | Ir | — | 0 |
| BD183 | LM183 | 3 | Ir | — | 0 |
| BD184 | LM184 | 3 | Ir | — | 0 |
| BD185 | LM185 | 3 | Ir | — | 0 |
| BD186 | LM186 | 3 | Ir | — | 0 |
| BD187 | LM187 | 3 | Ir | — | 0 |
| BD188 | LM188 | 3 | Ir | — | 0 |
| BD189 | LM189 | 3 | Ir | — | 0 |
| BD190 | LM190 | 3 | Ir | — | 0 |
| BD191 | LM191 | 3 | Ir | — | 0 |
| BD192 | LM192 | 3 | Ir | — | 0 |
| BD193 | LM193 | 3 | Ir | — | 0 |
| BD184 | LM194 | 3 | Ir | — | 0 |
| BD195 | LM195 | 3 | Ir | — | 0 |
| BD196 | LM196 | 3 | Ir | — | 0 |
| BD197 | LM197 | 3 | Ir | — | 0 |
| BD198 | LM198 | 3 | Ir | — | 0 |
| BD199 | LM199 | 3 | Ir | — | 0 |
| BD200 | LM200 | 3 | Ir | — | 0 |

TABLE 4

| Compound Name | L₁₀₁ | n101 | M₁₀₁ | L₁₀₂ | m101 |
|---|---|---|---|---|---|
| BD201 | LM201 | 3 | Ir | — | 0 |
| BD202 | LM202 | 3 | Ir | — | 0 |
| BD203 | LM203 | 3 | Ir | — | 0 |
| BD204 | LM204 | 3 | Ir | — | 0 |
| BD205 | LM205 | 3 | Ir | — | 0 |
| BD206 | LM206 | 3 | Ir | — | 0 |
| BD207 | LM207 | 3 | Ir | — | 0 |
| BD208 | LM208 | 3 | Ir | — | 0 |
| BD209 | LM209 | 3 | Ir | — | 0 |
| BD210 | LM210 | 3 | Ir | — | 0 |
| BD211 | LM211 | 3 | Ir | — | 0 |
| BD212 | LM212 | 3 | Ir | — | 0 |
| BD213 | LM213 | 3 | Ir | — | 0 |
| BD214 | LM214 | 3 | Ir | — | 0 |
| BD215 | LM215 | 3 | Ir | — | 0 |
| BD216 | LM216 | 3 | Ir | — | 0 |
| BD217 | LM217 | 3 | Ir | — | 0 |
| BD218 | LM218 | 3 | Ir | — | 0 |
| BD219 | LM219 | 3 | Ir | — | 0 |
| BD220 | LM220 | 3 | Ir | — | 0 |
| BD221 | LM221 | 3 | Ir | — | 0 |
| BD222 | LM222 | 3 | Ir | — | 0 |
| BD223 | LM223 | 3 | Ir | — | 0 |
| BD224 | LM224 | 3 | Ir | — | 0 |
| BD225 | LM225 | 3 | Ir | — | 0 |
| BD226 | LM226 | 3 | Ir | — | 0 |
| BD227 | LM227 | 3 | Ir | — | 0 |
| BD228 | LM228 | 3 | Ir | — | 0 |
| BD229 | LM229 | 3 | Ir | — | 0 |
| BD230 | LM230 | 3 | Ir | — | 0 |
| BD231 | LM231 | 3 | Ir | — | 0 |
| BD232 | LM232 | 3 | Ir | — | 0 |
| BD233 | LM233 | 3 | Ir | — | 0 |
| BD234 | LM234 | 3 | Ir | — | 0 |
| BD235 | LM235 | 3 | Ir | — | 0 |
| BD236 | LM236 | 3 | Ir | — | 0 |
| BD237 | LM237 | 3 | Ir | — | 0 |
| BD238 | LM238 | 3 | Ir | — | 0 |
| BD239 | LM239 | 3 | Ir | — | 0 |
| BD240 | LM240 | 3 | Ir | — | 0 |
| BD241 | LM241 | 3 | Ir | — | 0 |
| BD242 | LM242 | 3 | Ir | — | 0 |
| BD243 | LM243 | 3 | Ir | — | 0 |
| BD244 | LFM1 | 3 | Ir | — | 0 |
| BD245 | LFM2 | 3 | Ir | — | 0 |
| BD246 | LFM3 | 3 | Ir | — | 0 |
| BD247 | LFM4 | 3 | Ir | — | 0 |
| BD248 | LFM5 | 3 | Ir | — | 0 |
| BD249 | LFM6 | 3 | Ir | — | 0 |
| BD250 | LFM7 | 3 | Ir | — | 0 |
| BD251 | LFP1 | 3 | Ir | — | 0 |
| BD252 | LFP2 | 3 | Ir | — | 0 |
| BD253 | LFP3 | 3 | Ir | — | 0 |
| BD254 | LFP4 | 3 | Ir | — | 0 |
| BD255 | LFP5 | 3 | Ir | — | 0 |
| BD256 | LFP6 | 3 | Ir | — | 0 |
| BD257 | LFP7 | 3 | Ir | — | 0 |
| BD258 | LM47 | 2 | Ir | AN1 | 1 |
| BD259 | LM47 | 2 | Ir | AN2 | 1 |
| BD260 | LM47 | 2 | Ir | AN3 | 1 |
| BD261 | LM47 | 2 | Ir | AN4 | 1 |
| BD262 | LM47 | 2 | Ir | AN5 | 1 |
| BD263 | LM11 | 2 | Pt | — | 0 |
| BD264 | LM13 | 2 | Pt | — | 0 |
| BD265 | LM15 | 2 | Pt | — | 0 |
| BD266 | LM45 | 2 | Pt | — | 0 |
| BD267 | LM47 | 2 | Pt | — | 0 |
| BD268 | LM49 | 2 | Pt | — | 0 |
| BD269 | LM98 | 2 | Pt | — | 0 |
| BD270 | LM100 | 2 | Pt | — | 0 |
| BD271 | LM102 | 2 | Pt | — | 0 |
| BD272 | LM132 | 2 | Pt | — | 0 |
| BD273 | LM134 | 2 | Pt | — | 0 |
| BD274 | LM136 | 2 | Pt | — | 0 |
| BD275 | LM151 | 2 | Pt | — | 0 |
| BD276 | LM153 | 2 | Pt | — | 0 |
| BD277 | LM158 | 2 | Pt | — | 0 |
| BD278 | LM180 | 2 | Pt | — | 0 |
| BD279 | LM182 | 2 | Pt | — | 0 |
| BD280 | LM187 | 2 | Pt | — | 0 |
| BD281 | LM201 | 2 | Pt | — | 0 |
| BD282 | LM206 | 2 | Pt | — | 0 |
| BD283 | LM211 | 2 | Pt | — | 0 |
| BD284 | LM233 | 2 | Pt | — | 0 |
| BD285 | LM235 | 2 | Pt | — | 0 |
| BD286 | LM240 | 2 | Pt | — | 0 |
| BD287 | LFM5 | 2 | Pt | — | 0 |
| BD288 | LFM6 | 2 | Pt | — | 0 |
| BD289 | LFM7 | 2 | Pt | — | 0 |
| BD290 | LFP5 | 2 | Pt | — | 0 |
| BD291 | LFP6 | 2 | Pt | — | 0 |
| BD292 | LFP7 | 2 | Pt | — | 0 |
| BD293 | LM47 | 1 | Pt | AN1 | 1 |
| BD294 | LM47 | 1 | Pt | AN2 | 1 |
| BD295 | LM47 | 1 | Pt | AN3 | 1 |
| BD296 | LM47 | 1 | Pt | AN4 | 1 |
| BD297 | LM47 | 1 | Pt | AN5 | 1 |

LM1 to LM243, LFM1 to LFM7 and LFP1 to LFP7 in Tables 2 to 4 may be understood b referring to Formulae 11-1 to 11-3 and Tables 5 to 7:

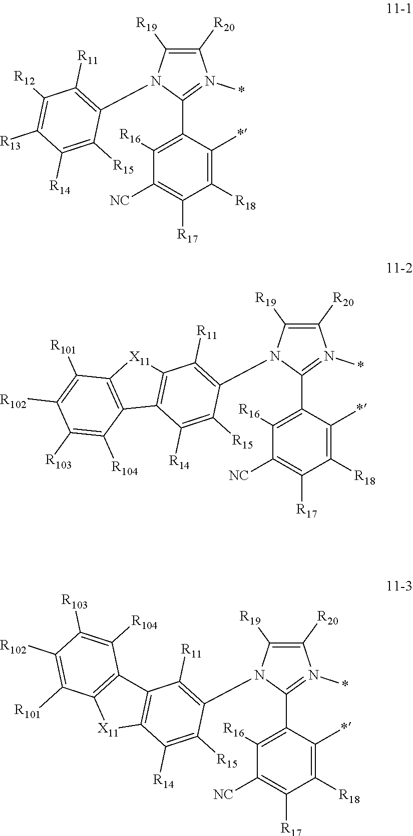

TABLE 5
Formula 11-1

| Ligand name | R₁₁ | R₁₂ | R₁₃ | R₁₄ | R₁₅ | R₁₆ | R₁₇ | R₁₈ | R₁₉ | R₂₀ |
|---|---|---|---|---|---|---|---|---|---|---|
| LM1 | X1 | H | X3 | H | X1 | H | H | H | H | D |
| LM2 | X1 | H | X3 | H | X1 | H | H | H | D | H |
| LM3 | X1 | H | X3 | H | X1 | H | H | H | D | D |
| LM4 | Y1 | H | X3 | H | Y1 | H | H | H | D | D |
| LM5 | Y2 | H | X3 | H | Y2 | H | H | H | D | D |
| LM6 | Y3 | H | X3 | H | Y3 | H | H | H | D | D |
| LM7 | Y3 | D | X3 | D | Y3 | H | H | H | D | D |
| LM8 | Y3 | D | X3 | D | Y3 | D | H | H | D | D |
| LM9 | Y3 | D | X3 | D | Y3 | D | D | H | D | D |
| LM10 | Y3 | D | X3 | D | Y3 | D | D | D | D | D |
| LM11 | Y3 | D | Y11 | D | Y3 | D | D | D | D | D |
| LM12 | Y3 | D | Y11 | D | Y3 | H | X1 | H | D | D |
| LM13 | Y3 | D | Y11 | D | Y3 | D | Y3 | D | D | D |
| LM14 | Y3 | D | Y11 | D | Y3 | H | X4 | H | D | D |
| LM15 | Y3 | D | Y11 | D | Y3 | D | Y12 | D | D | D |
| LM16 | X2 | H | X3 | H | X2 | H | H | H | H | D |
| LM17 | X2 | H | X3 | H | X2 | H | H | H | D | H |
| LM18 | X2 | H | X3 | H | X2 | H | H | H | D | D |
| LM19 | Y4 | H | X3 | H | Y4 | H | H | H | D | D |
| LM20 | Y5 | H | X3 | H | Y5 | H | H | H | D | D |
| LM21 | Y6 | H | X3 | H | Y6 | H | H | H | D | D |
| LM22 | Y7 | H | X3 | H | Y7 | H | H | H | D | D |
| LM23 | Y8 | H | X3 | H | Y8 | H | H | H | D | D |
| LM24 | Y9 | H | X3 | H | Y9 | H | H | H | D | D |
| LM25 | Y10 | H | X3 | H | Y10 | H | H | H | D | D |
| LM26 | Y10 | D | X3 | D | Y10 | H | H | H | D | D |
| LM27 | Y10 | D | X3 | D | Y10 | D | H | H | D | D |
| LM28 | Y10 | D | X3 | D | Y10 | D | D | H | D | D |
| LM29 | Y10 | D | X3 | D | Y10 | D | D | D | D | D |
| LM30 | Y10 | D | Y11 | D | Y10 | D | D | D | D | D |
| LM31 | Y10 | D | Y11 | D | Y10 | H | X1 | H | D | D |
| LM32 | Y10 | D | Y11 | D | Y10 | D | Y3 | D | D | D |
| LM33 | Y10 | D | Y11 | D | Y10 | H | X4 | H | D | D |
| LM34 | Y10 | D | Y11 | D | Y10 | D | Y12 | D | D | D |
| LM35 | X1 | H | X4 | H | X1 | H | H | H | H | D |
| LM36 | X1 | H | X4 | H | X1 | H | H | H | D | H |
| LM37 | X1 | H | X4 | H | X1 | H | H | H | D | D |
| LM38 | Y1 | H | X4 | H | Y1 | H | H | H | D | D |
| LM39 | Y2 | H | X4 | H | Y2 | H | H | H | D | D |
| LM40 | Y3 | H | X4 | H | Y3 | H | H | H | D | D |
| LM41 | Y3 | D | X4 | D | Y3 | H | H | H | D | D |
| LM42 | Y3 | D | X4 | D | Y3 | D | H | H | D | D |
| LM43 | Y3 | D | X4 | D | Y3 | D | D | H | D | D |
| LM44 | Y3 | D | X4 | D | Y3 | D | D | D | D | D |
| LM45 | Y3 | D | Y12 | D | Y3 | D | D | D | D | D |
| LM46 | Y3 | D | Y12 | D | Y3 | H | X1 | H | D | D |
| LM47 | Y3 | D | Y12 | D | Y3 | D | Y3 | D | D | D |
| LM48 | Y3 | D | Y12 | D | Y3 | H | X4 | H | D | D |
| LM49 | Y3 | D | Y12 | D | Y3 | D | Y12 | D | D | D |
| LM50 | X2 | H | X4 | H | X2 | H | H | H | H | D |
| LM51 | X2 | H | X4 | H | X2 | H | H | H | D | H |
| LM52 | X2 | H | X4 | H | X2 | H | H | H | D | D |
| LM53 | Y4 | H | X4 | H | Y4 | H | H | H | D | D |
| LM54 | Y5 | H | X4 | H | Y5 | H | H | H | D | D |
| LM55 | Y6 | H | X4 | H | Y6 | H | H | H | D | D |
| LM56 | Y7 | H | X4 | H | Y7 | H | H | H | D | D |
| LM57 | Y8 | H | X4 | H | Y8 | H | H | H | D | D |
| LM58 | Y9 | H | X4 | H | Y9 | H | H | H | D | D |
| LM59 | Y10 | H | X4 | H | Y10 | H | H | H | D | D |
| LM60 | Y10 | D | X4 | D | Y10 | H | H | H | D | D |
| LM61 | Y10 | D | X4 | D | Y10 | D | H | H | D | D |
| LM62 | Y10 | D | X4 | D | Y10 | D | D | H | D | D |
| LM63 | Y10 | D | X4 | D | Y10 | D | D | D | D | D |
| LM64 | Y10 | D | Y12 | D | Y10 | D | D | D | D | D |
| LM65 | Y10 | D | Y12 | D | Y10 | H | X1 | H | D | D |
| LM66 | Y10 | D | Y12 | D | Y10 | D | Y3 | D | D | D |
| LM67 | Y10 | D | Y12 | D | Y10 | H | X4 | H | D | D |
| LM68 | Y10 | D | Y12 | D | Y10 | D | Y12 | D | D | D |
| LM69 | X1 | H | X5 | H | X1 | H | H | H | H | D |
| LM70 | X1 | H | X5 | H | X1 | H | H | H | D | H |
| LM71 | X1 | H | X5 | H | X1 | H | H | H | D | D |
| LM72 | Y1 | H | X5 | H | Y1 | H | H | H | D | D |
| LM73 | Y2 | H | X5 | H | Y2 | H | H | H | D | D |
| LM74 | Y3 | H | X5 | H | Y3 | H | H | H | D | D |
| LM75 | Y3 | D | X5 | D | Y3 | H | H | H | D | D |
| LM76 | Y3 | D | X5 | D | Y3 | D | H | H | D | D |
| LM77 | Y3 | D | X5 | D | Y3 | D | D | H | D | D |
| LM78 | Y3 | D | X5 | D | Y3 | D | D | D | D | D |
| LM79 | Y3 | D | Y13 | D | Y3 | D | D | D | D | D |
| LM80 | Y3 | D | Y13 | D | Y3 | H | X1 | H | D | D |
| LM81 | Y3 | D | Y13 | D | Y3 | D | Y3 | D | D | D |
| LM82 | Y3 | D | Y13 | D | Y3 | H | X4 | H | D | D |
| LM83 | Y3 | D | Y13 | D | Y3 | D | Y12 | D | D | D |
| LM84 | X2 | H | X5 | H | X2 | H | H | H | H | D |
| LM85 | X2 | H | X5 | H | X2 | H | H | H | D | H |
| LM86 | X2 | H | X5 | H | X2 | H | H | H | D | D |
| LM87 | Y4 | H | X5 | H | Y4 | H | H | H | D | D |
| LM88 | Y5 | H | X5 | H | Y5 | H | H | H | D | D |
| LM89 | Y6 | H | X5 | H | Y6 | H | H | H | D | D |
| LM90 | Y7 | H | X5 | H | Y7 | H | H | H | D | D |
| LM91 | Y8 | H | X5 | H | Y8 | H | H | H | D | D |
| LM92 | Y9 | H | X5 | H | Y9 | H | H | H | D | D |
| LM93 | Y10 | H | X5 | H | Y10 | H | H | H | D | D |
| LM94 | Y10 | D | X5 | D | Y10 | H | H | H | D | D |
| LM95 | Y10 | D | X5 | D | Y10 | D | H | H | D | D |
| LM96 | Y10 | D | X5 | D | Y10 | D | D | H | D | D |
| LM97 | Y10 | D | X5 | D | Y10 | D | D | D | D | D |
| LM98 | Y10 | D | Y13 | D | Y10 | D | D | D | D | D |
| LM99 | Y10 | D | Y13 | D | Y10 | H | X1 | H | D | D |
| LM100 | Y10 | D | Y13 | D | Y10 | D | Y3 | D | D | D |
| LM101 | Y10 | D | Y13 | D | Y10 | H | X4 | H | D | D |
| LM102 | Y10 | D | Y13 | D | Y10 | D | Y12 | D | D | D |
| LM103 | X1 | H | X6 | H | X1 | H | H | H | H | D |
| LM104 | X1 | H | X6 | H | X1 | H | H | H | D | H |
| LM105 | X1 | H | X6 | H | X1 | H | H | H | D | D |
| LM106 | Y1 | H | X6 | H | Y1 | H | H | H | D | D |
| LM107 | Y2 | H | X6 | H | Y2 | H | H | H | D | D |
| LM108 | Y3 | H | X6 | H | Y3 | H | H | H | D | D |
| LM109 | Y3 | D | X6 | D | Y3 | H | H | H | D | D |
| LM110 | Y3 | D | X6 | D | Y3 | D | H | H | D | D |
| LM111 | Y3 | D | X6 | D | Y3 | D | D | H | D | D |
| LM112 | Y3 | D | X6 | D | Y3 | D | D | D | D | D |
| LM113 | Y3 | D | Y14 | D | Y3 | D | D | D | D | D |
| LM114 | Y3 | D | Y14 | D | Y3 | H | X1 | H | D | D |
| LM115 | Y3 | D | Y14 | D | Y3 | D | Y3 | D | D | D |
| LM116 | Y3 | D | Y14 | D | Y3 | H | X4 | H | D | D |
| LM117 | Y3 | D | Y14 | D | Y3 | D | Y12 | D | D | D |
| LM118 | X2 | H | X6 | H | X2 | H | H | H | H | D |
| LM119 | X2 | H | X6 | H | X2 | H | H | H | D | H |
| LM120 | X2 | H | X6 | H | X2 | H | H | H | D | D |
| LM121 | Y4 | H | X6 | H | Y4 | H | H | H | D | D |
| LM122 | Y5 | H | X6 | H | Y5 | H | H | H | D | D |
| LM123 | Y6 | H | X6 | H | Y6 | H | H | H | D | D |
| LM124 | Y7 | H | X6 | H | Y7 | H | H | H | D | D |
| LM125 | Y8 | H | X6 | H | Y8 | H | H | H | D | D |
| LM126 | Y9 | H | X6 | H | Y9 | H | H | H | D | D |
| LM127 | Y10 | H | X6 | H | Y10 | H | H | H | D | D |
| LM128 | Y10 | D | X6 | D | Y10 | H | H | H | D | D |
| LM129 | Y10 | D | X6 | D | Y10 | D | H | H | D | D |
| LM130 | Y10 | D | X6 | D | Y10 | D | D | H | D | D |
| LM131 | Y10 | D | X6 | D | Y10 | D | D | D | D | D |
| LM132 | Y10 | D | Y14 | D | Y10 | D | D | D | D | D |
| LM133 | Y10 | D | Y14 | D | Y10 | H | X1 | H | D | D |
| LM134 | Y10 | D | Y14 | D | Y10 | D | Y3 | D | D | D |
| LM135 | Y10 | D | Y14 | D | Y10 | H | X4 | H | D | D |
| LM136 | Y10 | D | Y14 | D | Y10 | D | Y12 | D | D | D |
| LM137 | X1 | H | X7 | H | X1 | H | H | H | H | D |
| LM138 | X1 | H | X7 | H | X1 | H | H | H | D | H |
| LM139 | X1 | H | X7 | H | X1 | H | H | H | D | D |
| LM140 | Y1 | H | X7 | H | Y1 | H | H | H | D | D |
| LM141 | Y2 | H | X7 | H | Y2 | H | H | H | D | D |
| LM142 | Y3 | H | X7 | H | Y3 | H | H | H | D | D |
| LM143 | Y3 | D | X7 | D | Y3 | H | H | H | D | D |
| LM144 | Y3 | D | X7 | D | Y3 | D | H | H | D | D |
| LM145 | Y3 | D | X7 | D | Y3 | D | D | H | D | D |
| LM146 | Y3 | D | X7 | D | Y3 | D | D | D | D | D |
| LM147 | Y3 | D | X8 | D | Y3 | D | D | D | D | D |
| LM148 | Y3 | D | Y16 | D | Y3 | D | D | D | D | D |
| LM149 | Y3 | D | Y17 | D | Y3 | D | D | D | D | D |
| LM150 | Y3 | D | Y18 | D | Y3 | D | D | D | D | D |
| LM151 | Y3 | D | Y15 | D | Y3 | D | D | D | D | D |
| LM152 | Y3 | D | Y15 | D | Y3 | H | X1 | H | D | D |
| LM153 | Y3 | D | Y15 | D | Y3 | D | Y3 | D | D | D |
| LM154 | Y3 | D | Y16 | D | Y3 | D | Y3 | D | D | D |
| LM155 | Y3 | D | Y17 | D | Y3 | D | Y3 | D | D | D |
| LM156 | Y3 | D | Y18 | D | Y3 | D | Y3 | D | D | D |
| LM157 | Y3 | D | Y15 | D | Y3 | H | X4 | H | D | D |
| LM158 | Y3 | D | Y15 | D | Y3 | D | Y12 | D | D | D |
| LM159 | Y3 | D | Y16 | D | Y3 | D | Y12 | D | D | D |
| LM160 | Y3 | D | Y17 | D | Y3 | D | Y12 | D | D | D |
| LM161 | Y3 | D | Y18 | D | Y3 | D | Y12 | D | D | D |
| LM162 | X2 | H | X7 | H | X2 | H | H | H | H | D |
| LM163 | X2 | H | X7 | H | X2 | H | H | H | D | H |
| LM164 | X2 | H | X7 | H | X2 | H | H | H | D | D |
| LM165 | Y4 | H | X7 | H | Y4 | H | H | H | D | D |
| LM166 | Y5 | H | X7 | H | Y5 | H | H | H | D | D |
| LM167 | Y6 | H | X7 | H | Y6 | H | H | H | D | D |
| LM168 | Y7 | H | X7 | H | Y7 | H | H | H | D | D |
| LM169 | Y8 | H | X7 | H | Y8 | H | H | H | D | D |
| LM170 | Y9 | H | X7 | H | Y9 | H | H | H | D | D |
| LM171 | Y10 | H | X7 | H | Y10 | H | H | H | D | D |
| LM172 | Y10 | D | X7 | D | Y10 | H | H | H | D | D |
| LM173 | Y10 | D | X7 | D | Y10 | D | H | H | D | D |
| LM174 | Y10 | D | X7 | D | Y10 | D | D | H | D | D |
| LM175 | Y10 | D | X7 | D | Y10 | D | D | D | D | D |
| LM176 | Y10 | D | X8 | D | Y10 | D | D | D | D | D |
| LM177 | Y10 | D | Y16 | D | Y10 | D | D | D | D | D |
| LM178 | Y10 | D | Y17 | D | Y10 | D | D | D | D | D |
| LM179 | Y10 | D | Y18 | D | Y10 | D | D | D | D | D |
| LM180 | Y10 | D | Y15 | D | Y10 | D | D | D | D | D |
| LM181 | Y10 | D | Y15 | D | Y10 | H | X1 | H | D | D |
| LM182 | Y10 | D | Y15 | D | Y10 | D | Y3 | D | D | D |
| LM183 | Y10 | D | Y16 | D | Y10 | D | Y3 | D | D | D |
| LM184 | Y10 | D | Y17 | D | Y10 | D | Y3 | D | D | D |
| LM185 | Y10 | D | Y18 | D | Y10 | D | Y3 | D | D | D |
| LM186 | Y10 | D | Y15 | D | Y10 | H | X4 | H | D | D |
| LM187 | Y10 | D | Y15 | D | Y10 | D | Y12 | D | D | D |
| LM188 | Y10 | D | Y16 | D | Y10 | D | Y12 | D | D | D |
| LM189 | Y10 | D | Y17 | D | Y10 | D | Y12 | D | D | D |
| LM190 | Y10 | D | Y18 | D | Y10 | D | Y12 | D | D | D |
| LM191 | X1 | X7 | H | H | X1 | H | H | H | H | D |
| LM192 | X1 | X7 | H | H | X1 | H | H | H | D | H |
| LM193 | X1 | X7 | H | H | X1 | H | H | H | D | D |
| LM194 | Y1 | X7 | H | H | Y1 | H | H | H | D | D |
| LM195 | Y2 | X7 | H | H | Y2 | H | H | H | D | D |
| LM196 | Y3 | X7 | H | H | Y3 | H | H | H | D | D |
| LM197 | Y3 | X7 | D | D | Y3 | H | H | H | D | D |
| LM198 | Y3 | X7 | D | D | Y3 | D | H | H | D | D |
| LM199 | Y3 | X7 | D | D | Y3 | D | D | H | D | D |
| LM200 | Y3 | X7 | D | D | Y3 | D | D | D | D | D |
| LM201 | Y3 | Y15 | D | D | Y3 | D | D | D | D | D |
| LM202 | Y3 | Y16 | D | D | Y3 | D | D | D | D | D |
| LM203 | Y3 | Y17 | D | D | Y3 | D | D | D | D | D |
| LM204 | Y3 | Y18 | D | D | Y3 | D | D | D | D | D |
| LM205 | Y3 | Y15 | D | D | Y3 | H | X1 | H | D | D |
| LM206 | Y3 | Y15 | D | D | Y3 | D | Y3 | D | D | D |
| LM207 | Y3 | Y16 | D | D | Y3 | D | Y3 | D | D | D |
| LM208 | Y3 | Y17 | D | D | Y3 | D | Y3 | D | D | D |
| LM209 | Y3 | Y18 | D | D | Y3 | D | Y3 | D | D | D |
| LM210 | Y3 | Y15 | D | D | Y3 | H | X4 | H | D | D |
| LM211 | Y3 | Y15 | D | D | Y3 | D | Y12 | D | D | D |
| LM212 | Y3 | Y16 | D | D | Y3 | D | Y12 | D | D | D |
| LM213 | Y3 | Y17 | D | D | Y3 | D | Y12 | D | D | D |
| LM214 | Y3 | Y18 | D | D | Y3 | D | Y12 | D | D | D |
| LM215 | X2 | X7 | H | H | X2 | H | H | H | H | D |
| LM216 | X2 | X7 | H | H | X2 | H | H | H | D | H |
| LM217 | X2 | X7 | H | H | X2 | H | H | H | D | D |
| LM218 | Y4 | X7 | H | H | Y4 | H | H | H | D | D |
| LM219 | Y5 | X7 | H | H | Y5 | H | H | H | D | D |
| LM220 | Y6 | X7 | H | H | Y6 | H | H | H | D | D |
| LM221 | Y7 | X7 | H | H | Y7 | H | H | H | D | D |
| LM222 | Y8 | X7 | H | H | Y8 | H | H | H | D | D |
| LM223 | Y9 | X7 | H | H | Y9 | H | H | H | D | D |
| LM224 | Y10 | X7 | H | H | Y10 | H | H | H | D | D |
| LM225 | Y10 | X7 | D | D | Y10 | H | H | H | D | D |
| LM226 | Y10 | X7 | D | D | Y10 | D | H | H | D | D |
| LM227 | Y10 | X7 | D | D | Y10 | D | D | H | D | D |
| LM228 | Y10 | X7 | D | D | Y10 | D | D | D | D | D |
| LM229 | Y10 | X8 | D | D | Y10 | D | D | D | D | D |
| LM230 | Y10 | Y16 | D | D | Y10 | D | D | D | D | D |
| LM231 | Y10 | Y17 | D | D | Y10 | D | D | D | D | D |
| LM232 | Y10 | Y18 | D | D | Y10 | D | D | D | D | D |
| LM233 | Y10 | Y15 | D | D | Y10 | D | D | D | D | D |
| LM234 | Y10 | Y15 | D | D | Y10 | H | X1 | H | D | D |
| LM235 | Y10 | Y15 | D | D | Y10 | D | Y3 | D | D | D |
| LM236 | Y10 | Y16 | D | D | Y10 | D | Y3 | D | D | D |
| LM237 | Y10 | Y17 | D | D | Y10 | D | Y3 | D | D | D |
| LM238 | Y10 | Y18 | D | D | Y10 | D | Y3 | D | D | D |
| LM239 | Y10 | Y15 | D | D | Y10 | H | X4 | H | D | D |
| LM240 | Y10 | Y15 | D | D | Y10 | D | Y12 | D | D | D |
| LM241 | Y10 | Y16 | D | D | Y10 | D | Y12 | D | D | D |
| LM242 | Y10 | Y17 | D | D | Y10 | D | Y12 | D | D | D |
| LM243 | Y10 | Y18 | D | D | Y10 | D | Y12 | D | D | D |

TABLE 6
Formula 11-2

| Ligand name | R₁₁ | X₁₁ | R₁₀₁ | R₁₀₂ | R₁₀₃ | R₁₀₄ | R₁₄ | R₁₅ | R₁₆ | R₁₇ | R₁₈ | R₁₉ | R₂₀ |
|---|---|---|---|---|---|---|---|---|---|---|---|---|---|
| LFM1 | Y10 | N—Ph | D | D | D | D | D | Y10 | D | D | D | D | D |
| LFM2 | Y10 | S | D | D | D | D | D | Y10 | D | D | D | D | D |
| LFM3 | Y10 | O | D | D | D | D | D | Y10 | D | D | D | D | D |
| LFM4 | Y3 | O | D | D | D | D | D | Y3 | D | D | D | D | D |
| LFM5 | Y10 | O | D | D | D | D | D | Y10 | D | D | D | D | D |
| LFM6 | Y10 | O | D | D | D | D | D | Y10 | D | Y3 | D | D | D |
| LFM7 | Y10 | O | D | D | D | D | D | Y10 | D | Y12 | D | D | D |

TABLE 7
Formula 11-3

| Ligand name | R₁₁ | X₁₁ | R₁₀₁ | R₁₀₂ | R₁₀₃ | R₁₀₄ | R₁₄ | R₁₅ | R₁₆ | R₁₇ | R₁₈ | R₁₉ | R₂₀ |
|---|---|---|---|---|---|---|---|---|---|---|---|---|---|
| LFP1 | Y10 | N—Ph | D | D | D | D | D | Y10 | D | D | D | D | D |
| LFP2 | Y10 | S | D | D | D | D | D | Y10 | D | D | D | D | D |
| LFP3 | Y10 | O | D | D | D | D | D | Y10 | D | D | D | D | D |
| LFP4 | Y3 | O | D | D | D | D | D | Y3 | D | D | D | D | D |
| LFP5 | Y10 | O | D | D | D | D | D | Y10 | D | D | D | D | D |
| LFP6 | Y10 | O | D | D | D | D | D | Y10 | D | Y3 | D | D | D |
| LFP7 | Y10 | O | D | D | D | D | D | Y10 | D | Y12 | D | D | D |

X1 to X10 and Y1 to Y18 in Tables 5-7 are the same as described below, and Ph in the tables refers to a phenyl group:

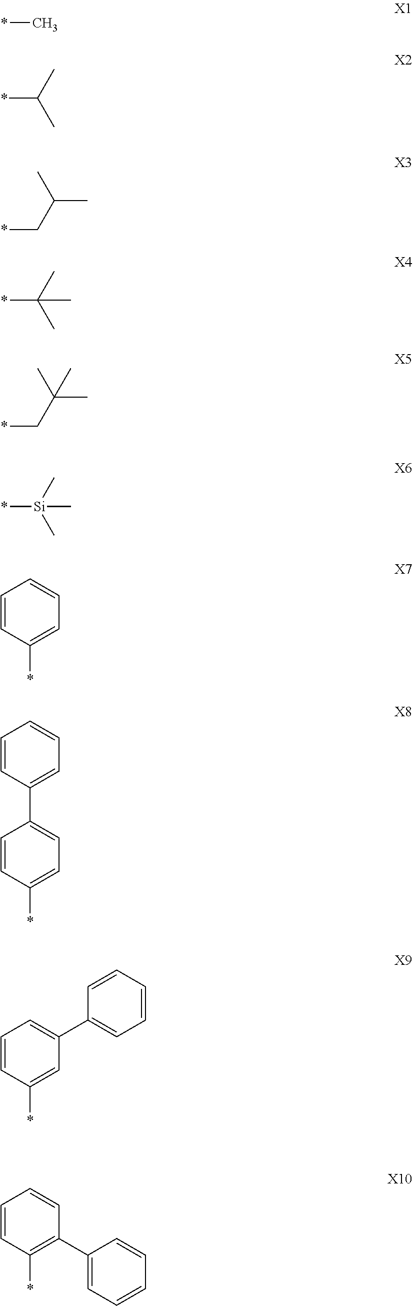

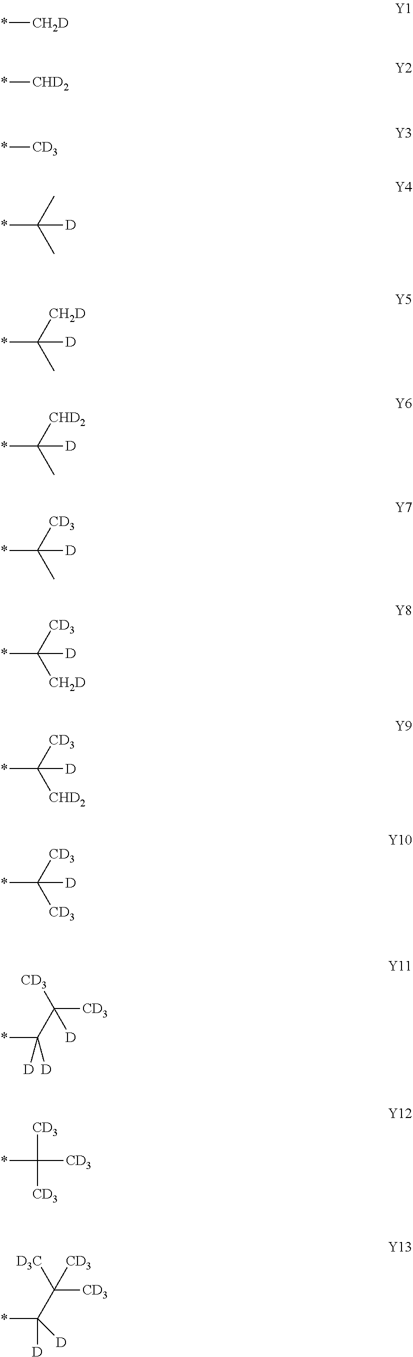

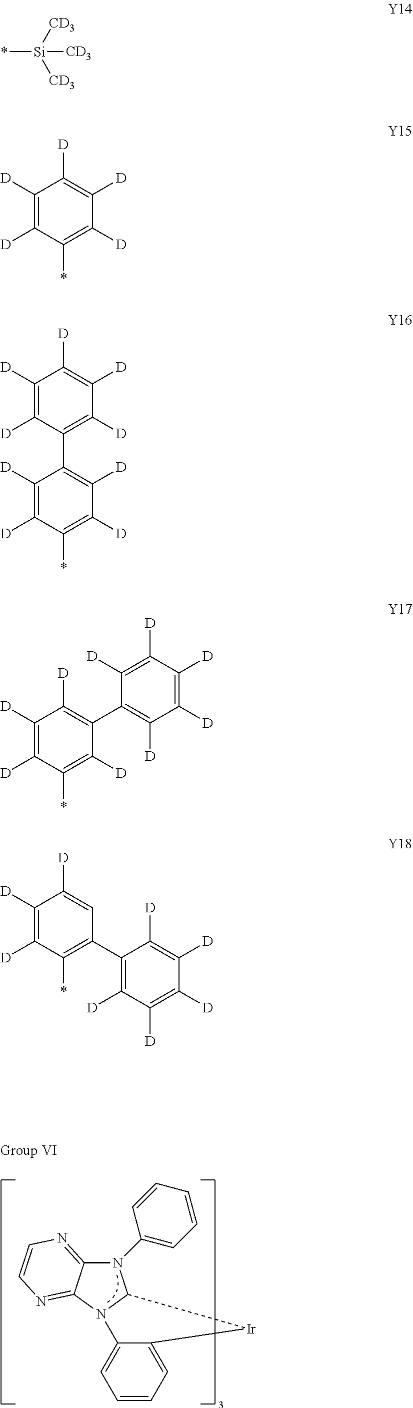

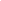

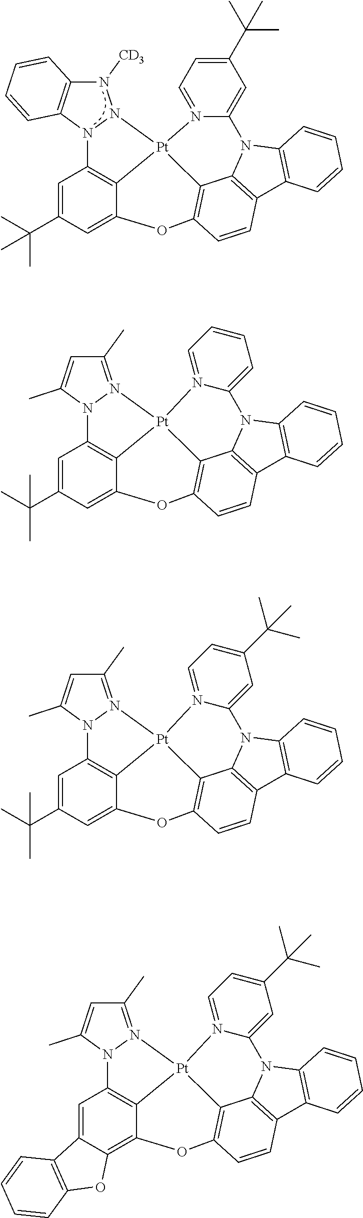

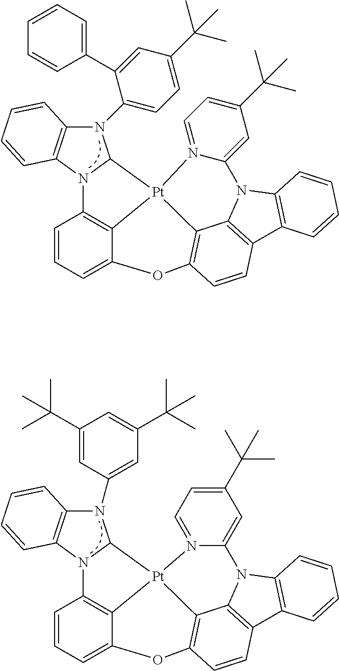

In one or more embodiments, the sensitizer may be a TADF emitter that satisfies Condition 7:

ΔE_{ST}≤0.3 eV Condition 7

wherein, in Condition 7,

ΔE_{ST} is the difference between the lowest excited singlet energy level and the lowest excited triplet energy level of the sensitizer.

In one or more embodiments, the sensitizer may include the thermally activated delayed fluorescence emitter represented by Formula 201 or 202:

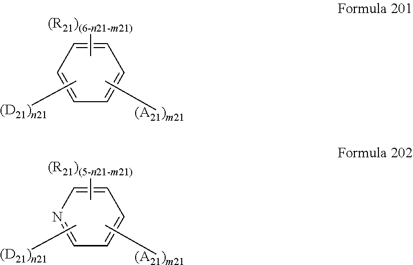

wherein, in Formulae 201 and 202,

A₂₁ is an acceptor group,

D₂₁ is a donor group,

m21 may be 1, 2, or 3, and n21 may be 1, 2, or 3,

the sum of n21 and m21 in Formula 201 may be 6 or less, and the sum of n21

and m21 in Formula 202 may be 5 or less,

R₂₁ may be hydrogen, deuterium, —F, —Cl, —Br, —I, SF₅, a hydroxyl group, a cyano group, a nitro group, an amidino group, a hydrazine group, a hydrazone group, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₇-C₆₀ alkyl aryl group, a substituted or unsubstituted C₇-C₆₀ aryl alkyl group, a substituted or unsubstituted C₆-C₆₀ aryloxy group, a substituted or unsubstituted C₆-C₆₀ arylthio group, a substituted or unsubstituted C₁-C₆₀ alkylheteroaryl group, a substituted or unsubstituted C₂-C₆₀ heteroaryl alkyl group, a substituted or unsubstituted C₁-C₆₀ heteroaryloxy group, a substituted or unsubstituted C₂-C₆₀ heteroarylthio group, a substituted or unsubstituted monovalent non-aromatic condensed polycyclic group, a substituted or unsubstituted monovalent non-aromatic condensed heteropolycyclic group, —Si(Q₁)(Q₂)(Q₃), —B(Q₁)(Q₂), —N(Q₁)(Q₂), —P(Q₁)(Q₂), —C(═O)(Q₁), —S(═O)(Q₁), —S(═O)₂(Q₁), —P(═O)(Q₁)(Q₂), or —P(═S)(Q₁)(Q₂), and a plurality of R₂₁(s) may optionally be bonded to form a substituted or unsubstituted C₅-C₃₀ carbocyclic group or a substituted or unsubstituted C₁-C₃₀ heterocyclic group,

Q₁ to Q₃ may each independently be hydrogen, deuterium, —F, —Cl, —Br, —I, a hydroxyl group, a cyano group, a nitro group, an amidino group, a hydrazine group, a hydrazone group, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₇-C₆₀ aryl alkyl group, a C₆-C₆₀ aryloxy group, a C₆-C₆₀ arylthio group, a C₁-C₆₀ heteroaryl group, a C₂-C₆₀ alkyl heteroaryl group, a C₂-C₆₀ heteroaryl alkyl group, a C₁-C₆₀ heteroaryloxy group, a C₁-C₆₀ heteroarylthio group, a monovalent non-aromatic condensed polycyclic group, a monovalent non-aromatic condensed heteropolycyclic group, a C₁-C₆₀ alkyl group that is substituted with at least one of deuterium, —F, a cyano group, a C₁-C₆₀ alkyl group, or a C₆-C₆₀ aryl group, or a C₆-C₆₀ aryl group that is substituted with at least one of deuterium, —F, a cyano group, a C₁-C₆₀ alkyl group, or a C₆-C₆₀ aryl group.

For example, A₂₁ in Formula 201 and 202 may be a substituted unsubstituted π electron-deficient nitrogen-free cyclic group.

In one or more embodiments, the π electron-deficient nitrogen-free cyclic group may be a benzene group, a heptalene group, an indene group, a naphthalene group, an azulene group, an indacene group, acenaphthylene group, a fluorene group, a spiro-bifluorene group, a benzofluorene group, a dibenzofluorene group, a phenalene group, a phenanthrene group, an anthracene group, a fluoranthene group, a triphenylene group, a pyrene group, a chrysene group, a naphthacene group, a picene group, a perylene group, a pentacene group, a hexacene group, a rubicene group, a coronene group, an ovalene group, a pyrrole group, an isoindole group, an indole group, a furan group, a thiophene group, a benzofuran group, a benzothiophene group, a benzocarbazole group, a dibenzocarbazole group, a dibenzofuran group, a dibenzothiophene group, a dibenzothiophene sulfone group, a carbazole group, a dibenzosilole group, an indenocarbazole group, an indolocarbazole group, a benzofurocarbazole group, a benzothienocarbazole group, a triindolobenzene group; or a condensed cyclic group of two or more π electron-deficient nitrogen-free cyclic groups, but embodiments of the present disclosure are not limited thereto.

For example, D₂₁ in Formulae 201 and 202 may be:

—F, a cyano group, or a π-electron deficient nitrogen-containing cyclic group;

a C₁-C₆₀ alkyl group, a π-electron deficient nitrogen-containing cyclic group, or an π electron-deficient nitrogen-free cyclic group, each substituted with at least one of —F or a cyano group; or

a π-electron deficient nitrogen-containing cyclic group, substituted with at least one of deuterium, a C₁-C₆₀ alkyl group, a π-electron deficient nitrogen-containing cyclic group, or a π electron-deficient nitrogen-free cyclic group.

In one or more embodiments, the π-electron deficient nitrogen-free cyclic group is the same as described above.

The term “π-electron deficient nitrogen-containing cyclic group” used herein refers to a cyclic group having at least one —N═moiety, and, for example, may be an imidazole group, a pyrazole group, a thiazole group, an isothiazole group, an oxazole group, an isoxazole group, a pyridine group, a pyrazine group, a pyridazine group, a pyrimidine group, an indazole group, a purine group, a quinoline group, an isoquinoline group, a benzoquinoline group, a phthalazine group, a naphthyridine group, a quinoxaline group, a quinazoline group, a cinnoline group, a phenanthridine group, an acridine group, a phenanthroline group, a phenazine group, a benzimidazole group, an isobenzothiazole group, a benzoxazole group, an isobenzoxazole group, a triazole group, a tetrazole group, an oxadiazole group, a triazine group, a thiadiazole group, an imidazopyridine group, an imidazopyrimidine group, an azacarbazole group, and a benzimidazolobenzimidazole group; or a condensed cyclic group in which two or more π electron-deficient nitrogen-containing cyclic groups are condensed with each other.

In one or more embodiments, the sensitizer may be a compound of one of Groups VII to XI, but embodiments of the present disclosure are not limited thereto:

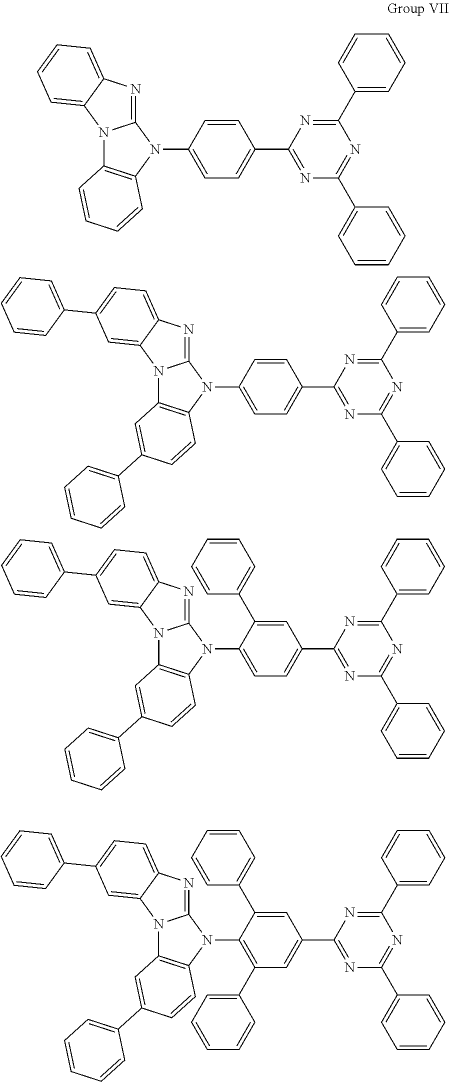

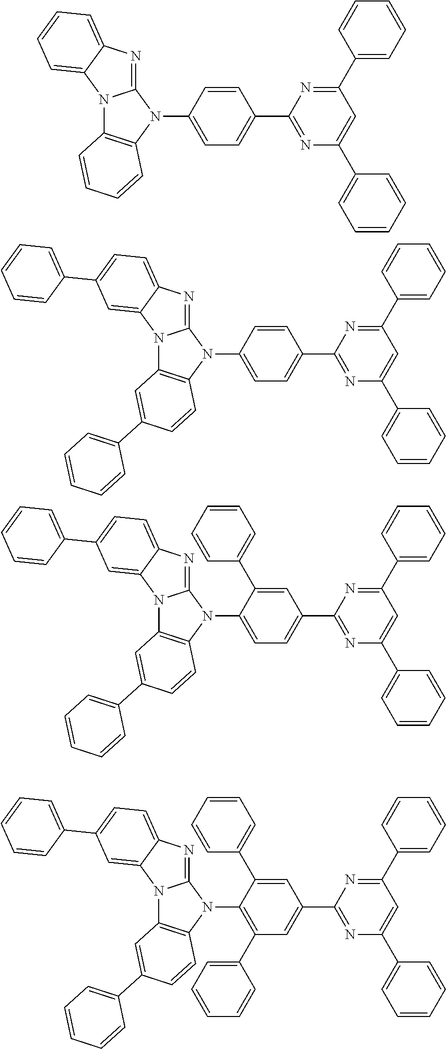

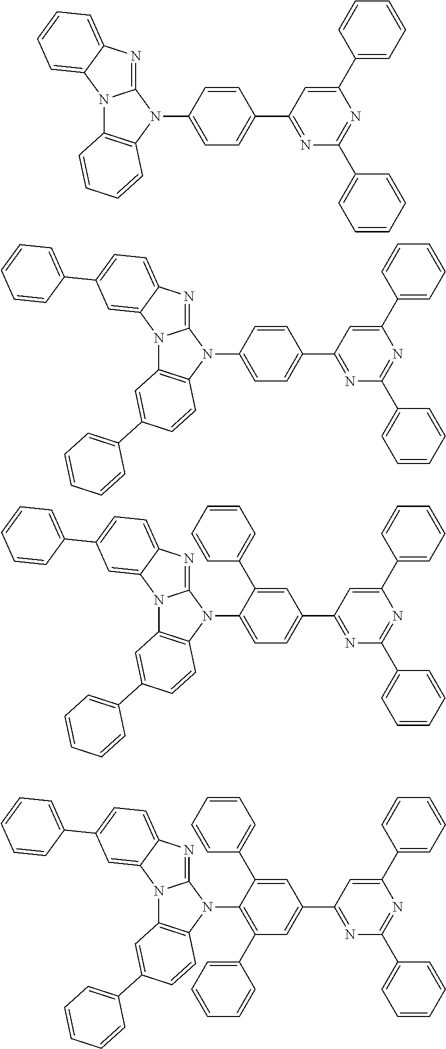

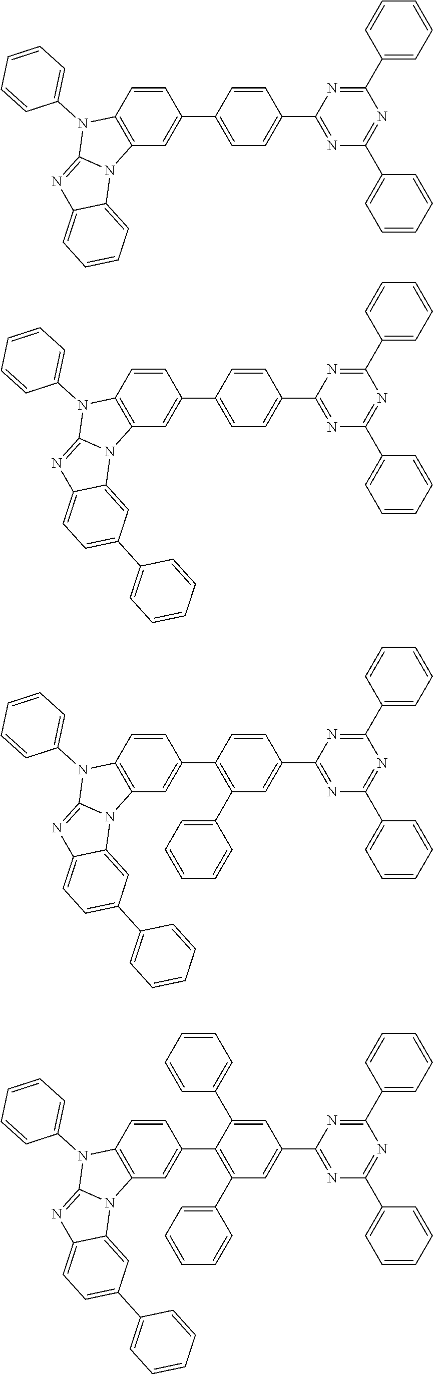 [SMILES: c1ccc(-c2nc(-c3ccccc3)nc(-c3ccc(-c4ccc5c(c4)n4c6ccccc6nc4n5-c4ccccc4)cc3)n2)cc1 ; c1ccc(-c2ccc3nc4n(-c5ccccc5)c5ccc(-c6ccc(-c7nc(-c8ccccc8)nc(-c8ccccc8)n7)cc6)cc5n4c3c2)cc1 ; c1ccc(-c2ccc3nc4n(-c5ccccc5)c5ccc(-c6ccc(-c7nc(-c8ccccc8)nc(-c8ccccc8)n7)cc6-c6ccccc6)cc5n4c3c2)cc1 ; c1ccc(-c2ccc3nc4n(-c5ccccc5)c5ccc(-c6c(-c7ccccc7)cc(-c7nc(-c8ccccc8)nc(-c8ccccc8)n7)cc6-c6ccccc6)cc5n4c3c2)cc1]

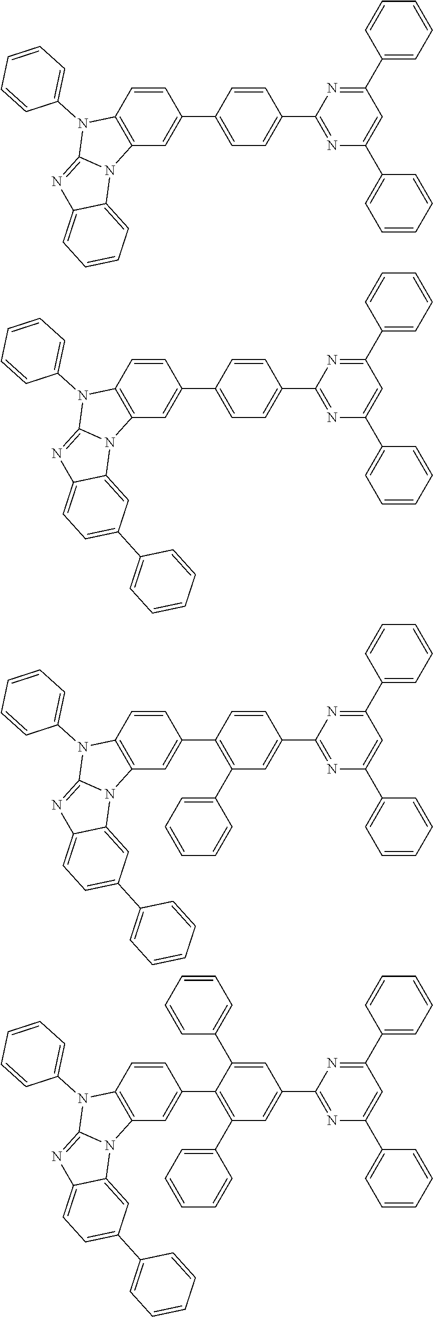

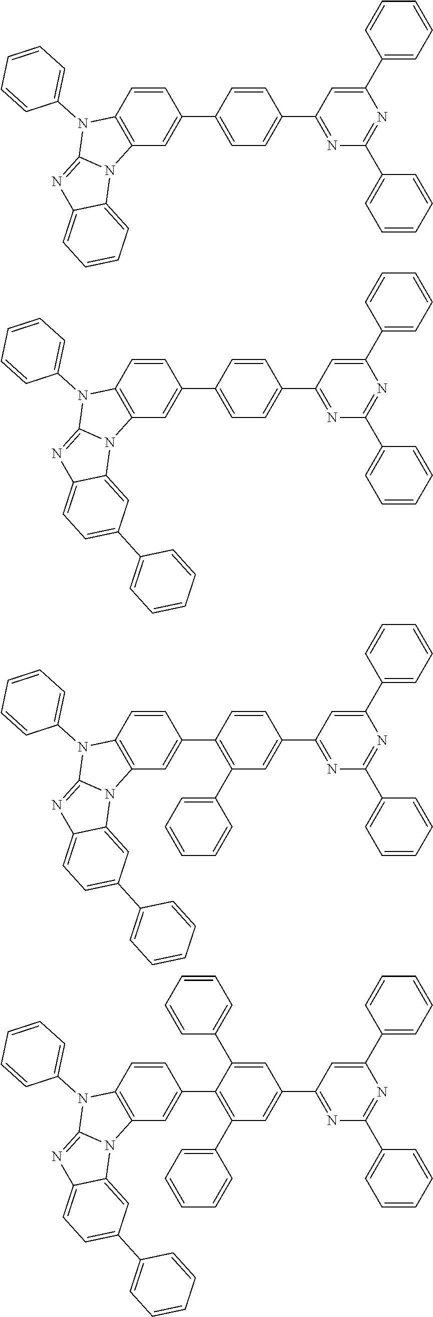

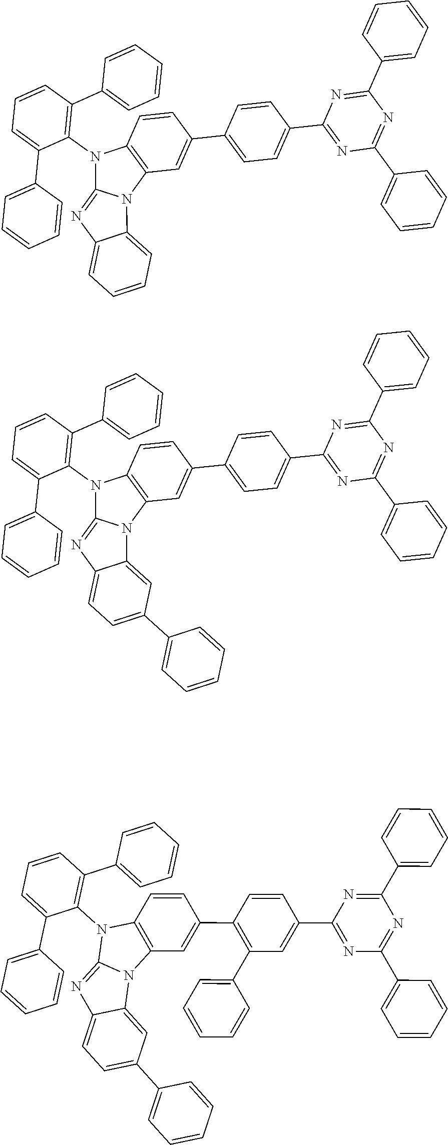 [SMILES: c1ccc(-c2nc(-c3ccccc3)nc(-c3ccc(-c4ccc5c(c4)n4c6ccccc6nc4n5-c4c(-c5ccccc5)cccc4-c4ccccc4)cc3)n2)cc1 ; c1ccc(-c2ccc3nc4n(-c5c(-c6ccccc6)cccc5-c5ccccc5)c5ccc(-c6ccc(-c7nc(-c8ccccc8)nc(-c8ccccc8)n7)cc6)cc5n4c3c2)cc1 ; c1ccc(-c2ccc3nc4n(-c5c(-c6ccccc6)cccc5-c5ccccc5)c5ccc(-c6ccc(-c7nc(-c8ccccc8)nc(-c8ccccc8)n7)cc6-c6ccccc6)cc5n4c3c2)cc1]

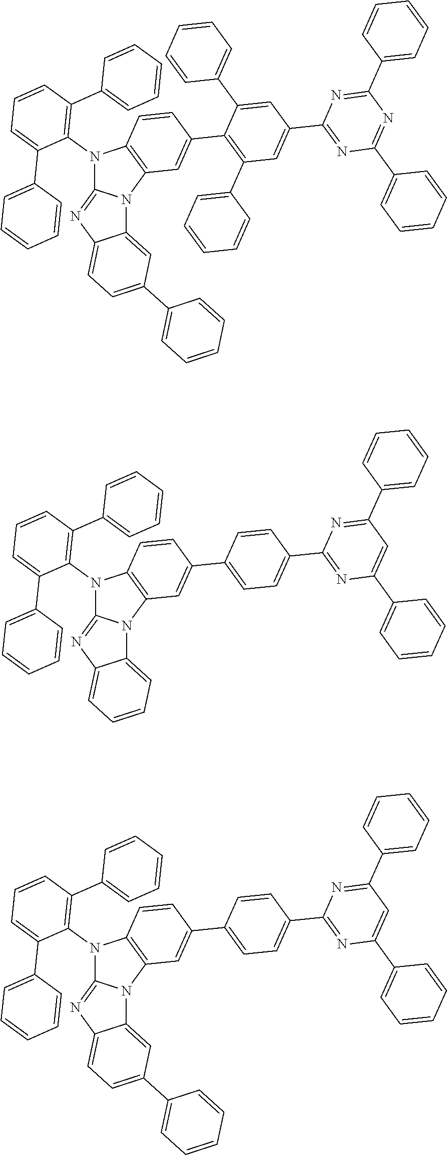 [SMILES: c1ccc(-c2ccc3nc4n(-c5c(-c6ccccc6)cccc5-c5ccccc5)c5ccc(-c6c(-c7ccccc7)cc(-c7nc(-c8ccccc8)nc(-c8ccccc8)n7)cc6-c6ccccc6)cc5n4c3c2)cc1 ; c1ccc(-c2cc(-c3ccccc3)nc(-c3ccc(-c4ccc5c(c4)n4c6ccccc6nc4n5-c4c(-c5ccccc5)cccc4-c4ccccc4)cc3)n2)cc1 ; c1ccc(-c2ccc3nc4n(-c5c(-c6ccccc6)cccc5-c5ccccc5)c5ccc(-c6ccc(-c7nc(-c8ccccc8)cc(-c8ccccc8)n7)cc6)cc5n4c3c2)cc1]

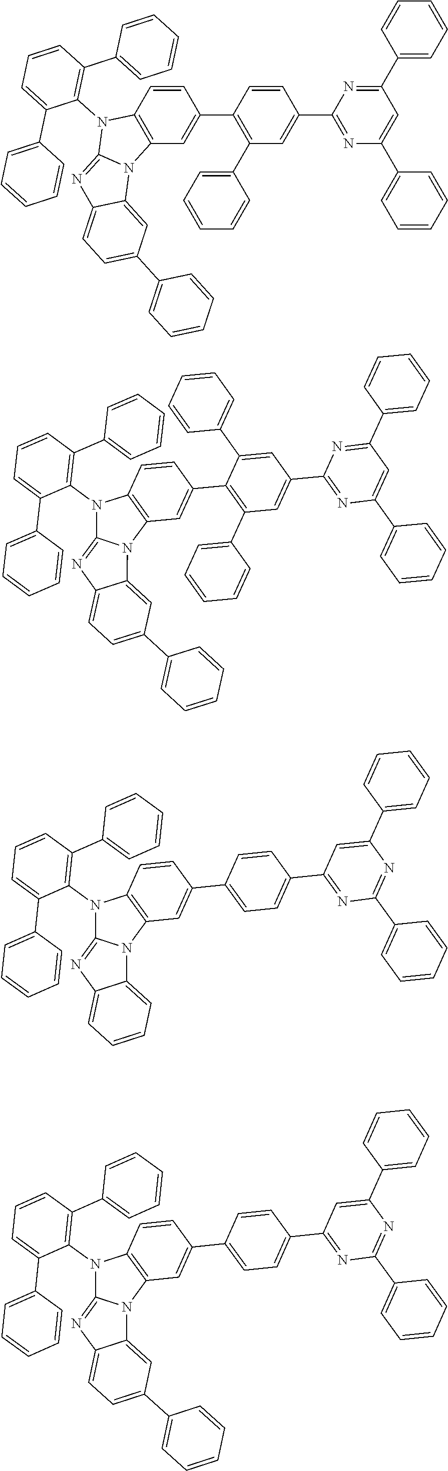

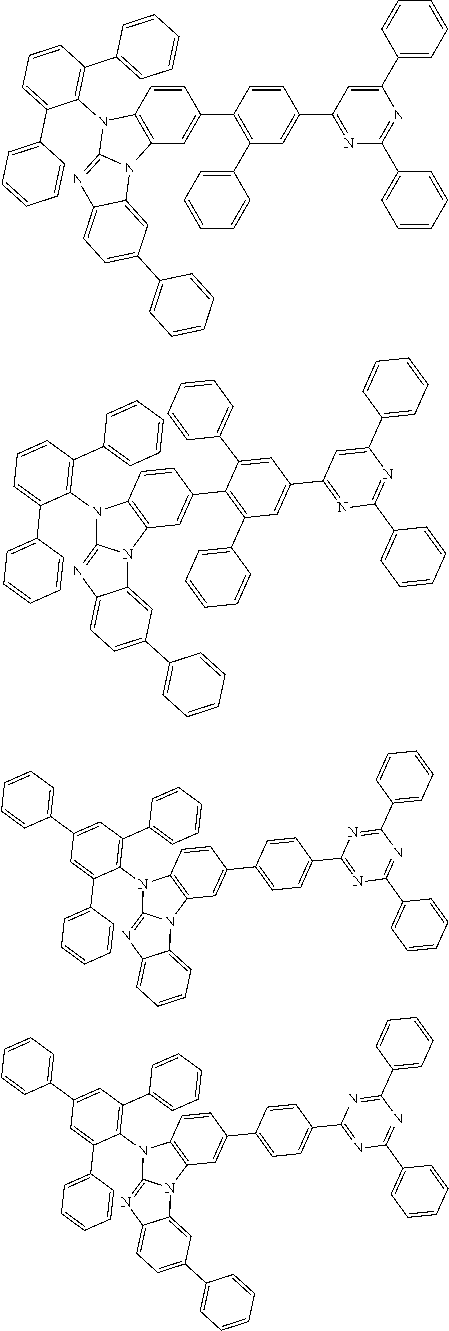 [SMILES: c1ccc(-c2ccc3nc4n(-c5c(-c6ccccc6)cccc5-c5ccccc5)c5ccc(-c6ccc(-c7cc(-c8ccccc8)nc(-c8ccccc8)n7)cc6-c6ccccc6)cc5n4c3c2)cc1 ; c1ccc(-c2ccc3nc4n(-c5c(-c6ccccc6)cccc5-c5ccccc5)c5ccc(-c6c(-c7ccccc7)cc(-c7cc(-c8ccccc8)nc(-c8ccccc8)n7)cc6-c6ccccc6)cc5n4c3c2)cc1 ; c1ccc(-c2cc(-c3ccccc3)c(-n3c4ccc(-c5ccc(-c6nc(-c7ccccc7)nc(-c7ccccc7)n6)cc5)cc4n4c5ccccc5nc34)c(-c3ccccc3)c2)cc1 ; c1ccc(-c2cc(-c3ccccc3)c(-n3c4ccc(-c5ccc(-c6nc(-c7ccccc7)nc(-c7ccccc7)n6)cc5)cc4n4c5cc(-c6ccccc6)ccc5nc34)c(-c3ccccc3)c2)cc1]

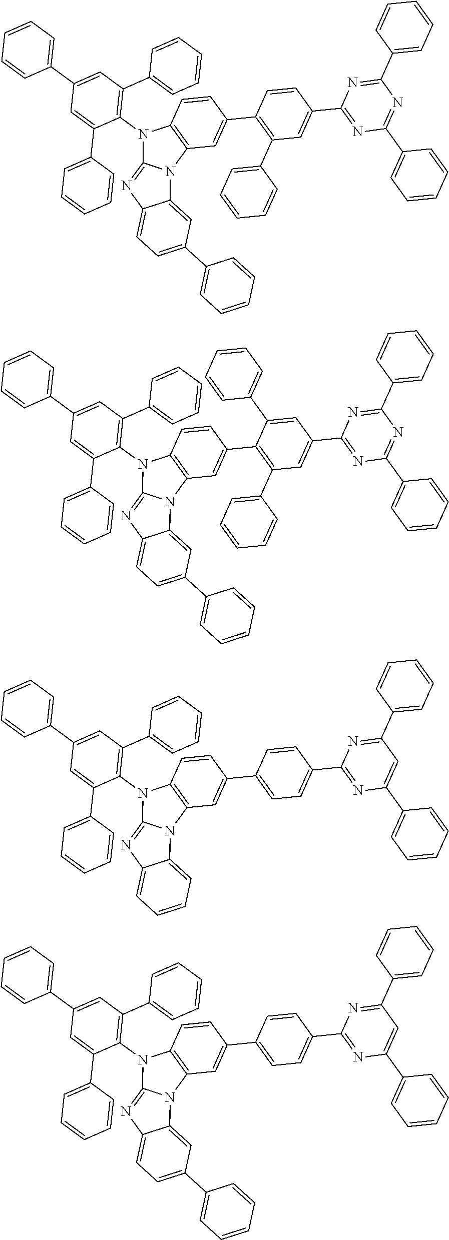

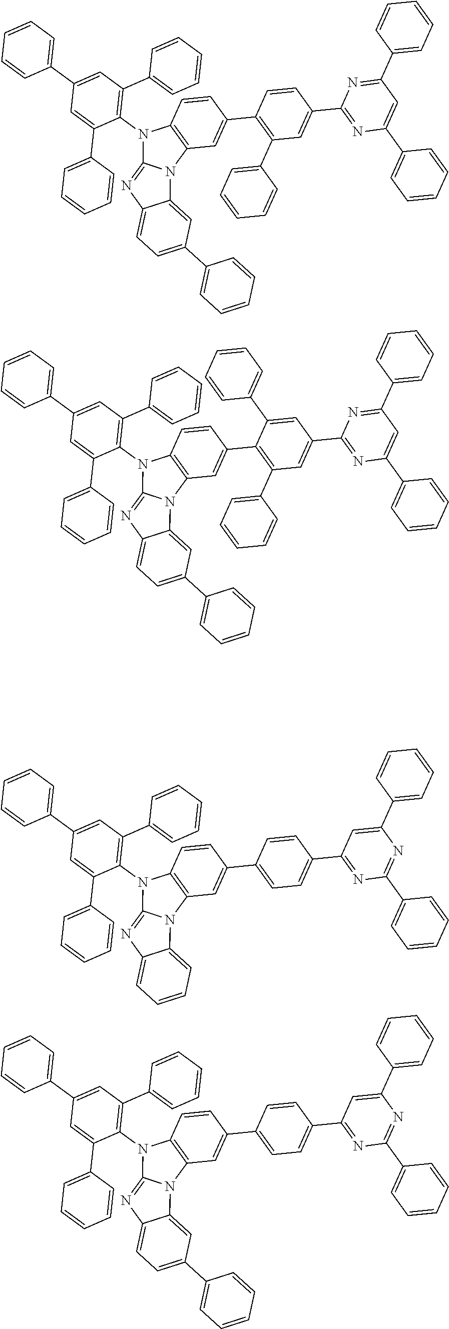

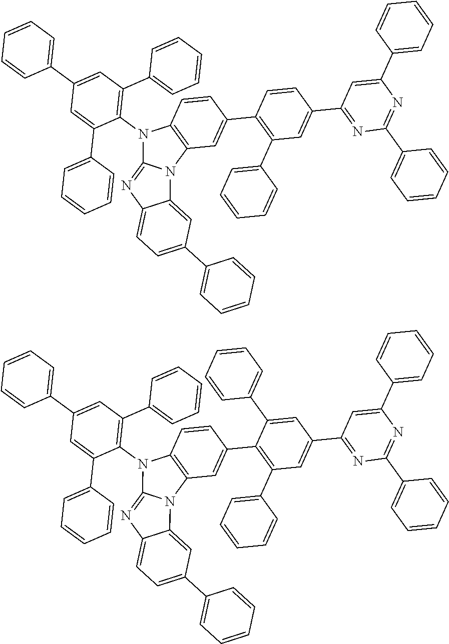

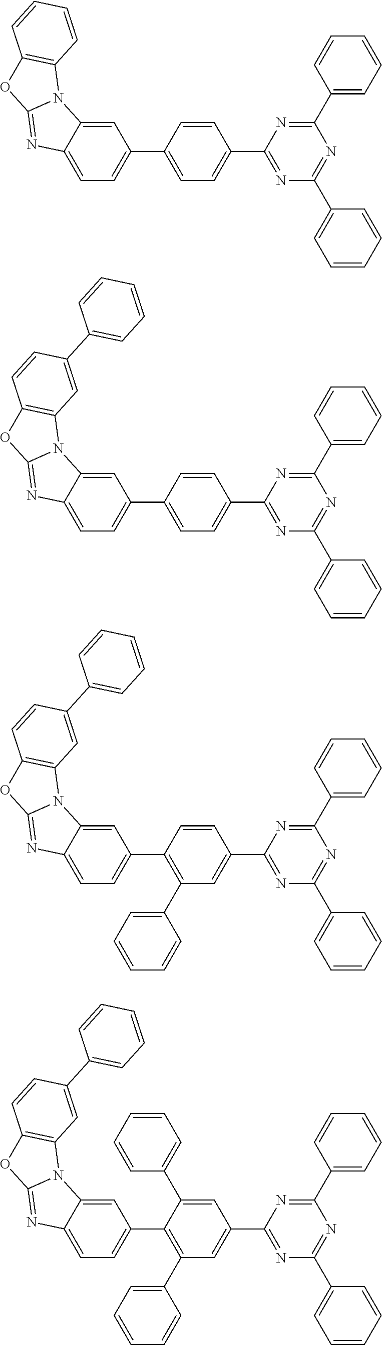

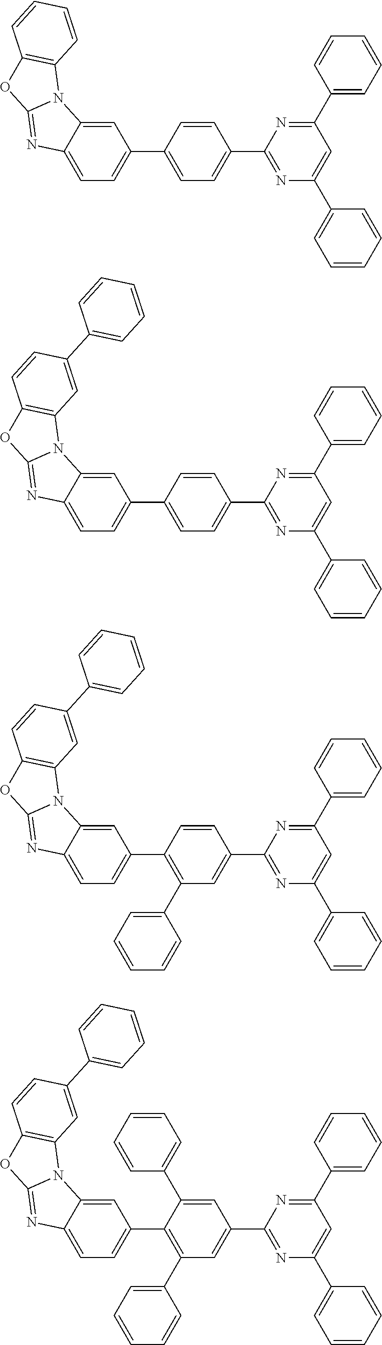

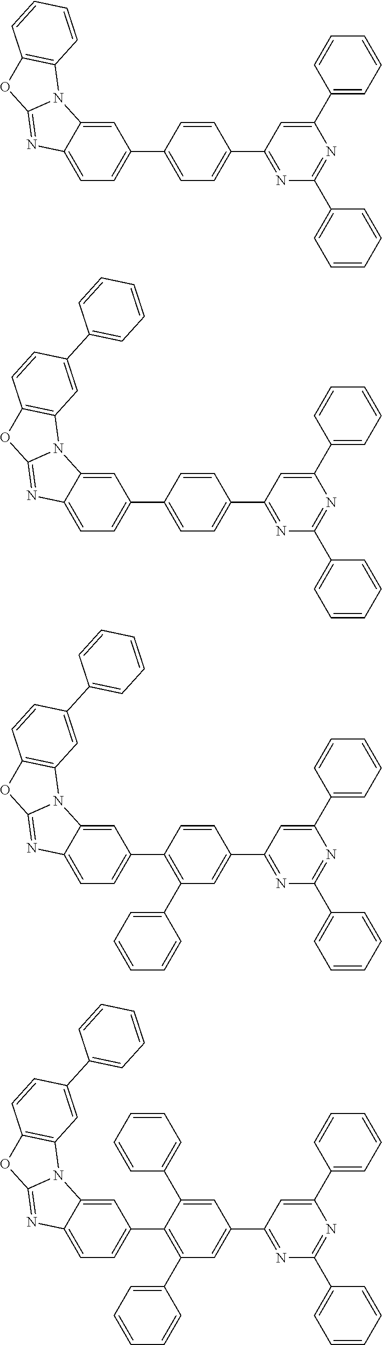

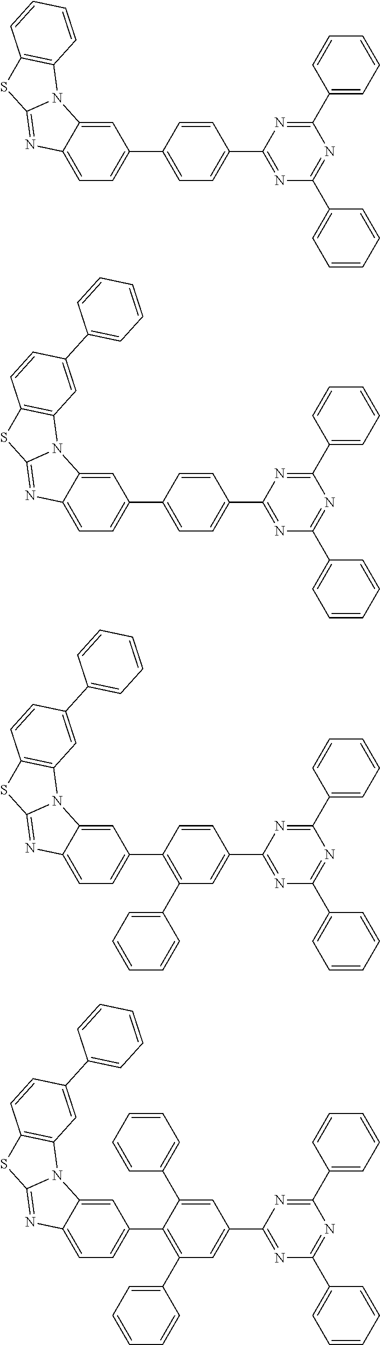

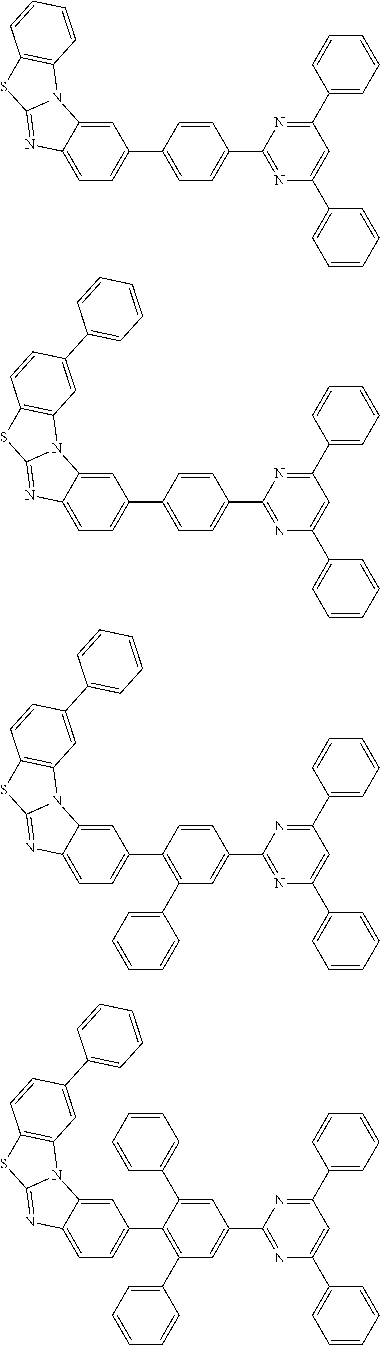

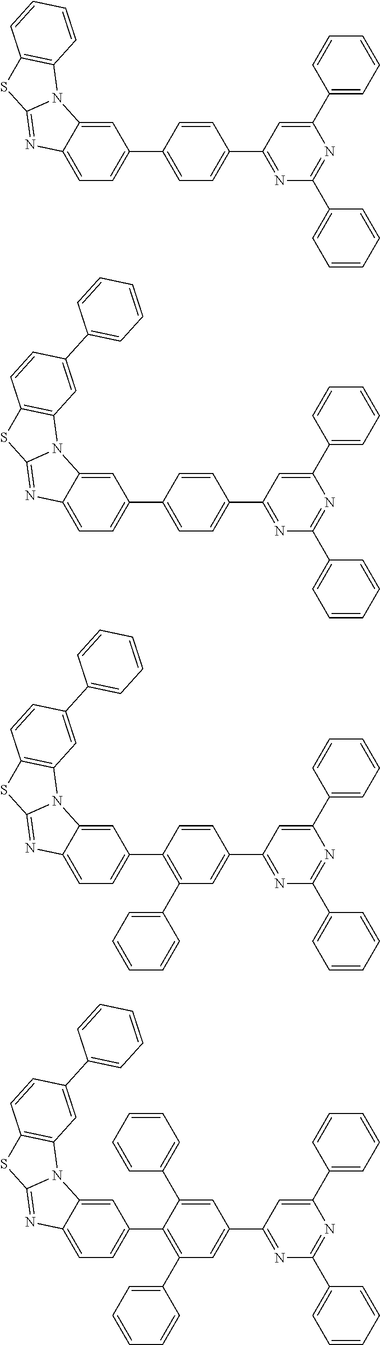

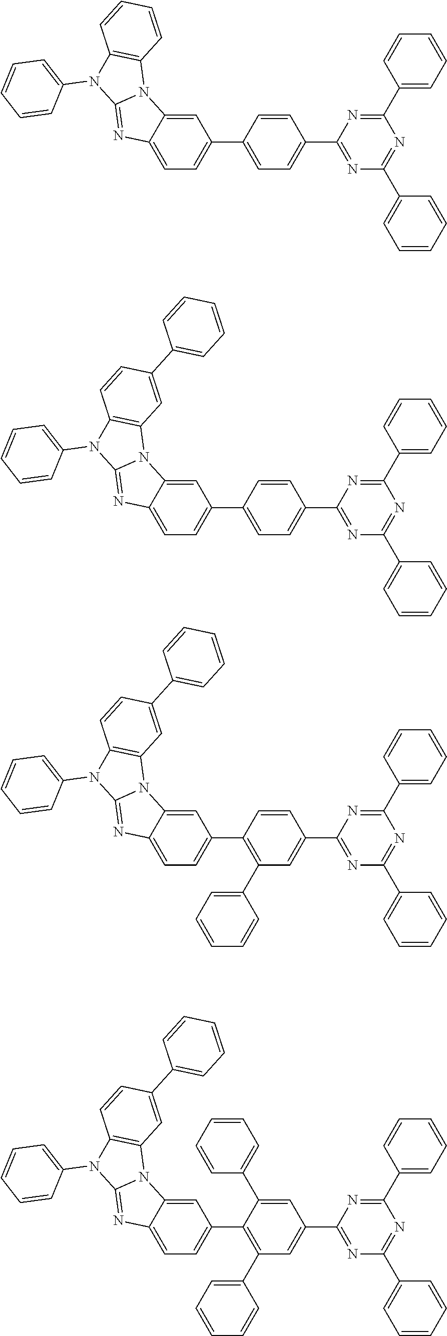 [SMILES: c1ccc(-c2nc(-c3ccccc3)nc(-c3ccc(-c4ccc5nc6n(-c7ccccc7)c7ccccc7n6c5c4)cc3)n2)cc1 ; c1ccc(-c2ccc3c(c2)n2c4cc(-c5ccc(-c6nc(-c7ccccc7)nc(-c7ccccc7)n6)cc5)ccc4nc2n3-c2ccccc2)cc1 ; c1ccc(-c2ccc3c(c2)n2c4cc(-c5ccc(-c6nc(-c7ccccc7)nc(-c7ccccc7)n6)cc5-c5ccccc5)ccc4nc2n3-c2ccccc2)cc1 ; c1ccc(-c2ccc3c(c2)n2c4cc(-c5c(-c6ccccc6)cc(-c6nc(-c7ccccc7)nc(-c7ccccc7)n6)cc5-c5ccccc5)ccc4nc2n3-c2ccccc2)cc1]

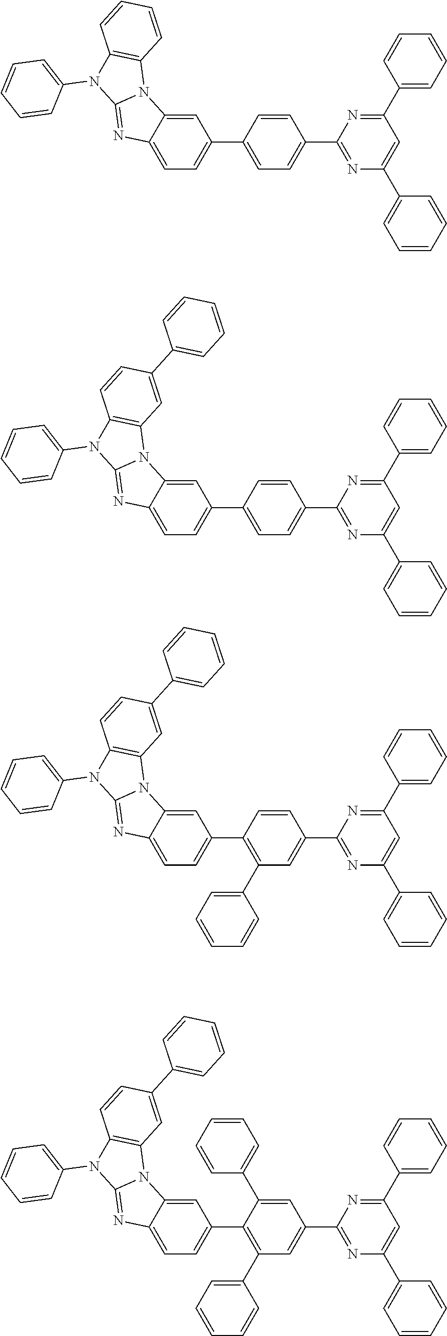 [SMILES: c1ccc(-c2cc(-c3ccccc3)nc(-c3ccc(-c4ccc5nc6n(-c7ccccc7)c7ccccc7n6c5c4)cc3)n2)cc1 ; c1ccc(-c2ccc3c(c2)n2c4cc(-c5ccc(-c6nc(-c7ccccc7)cc(-c7ccccc7)n6)cc5)ccc4nc2n3-c2ccccc2)cc1 ; c1ccc(-c2ccc3c(c2)n2c4cc(-c5ccc(-c6nc(-c7ccccc7)cc(-c7ccccc7)n6)cc5-c5ccccc5)ccc4nc2n3-c2ccccc2)cc1 ; c1ccc(-c2ccc3c(c2)n2c4cc(-c5c(-c6ccccc6)cc(-c6nc(-c7ccccc7)cc(-c7ccccc7)n6)cc5-c5ccccc5)ccc4nc2n3-c2ccccc2)cc1]

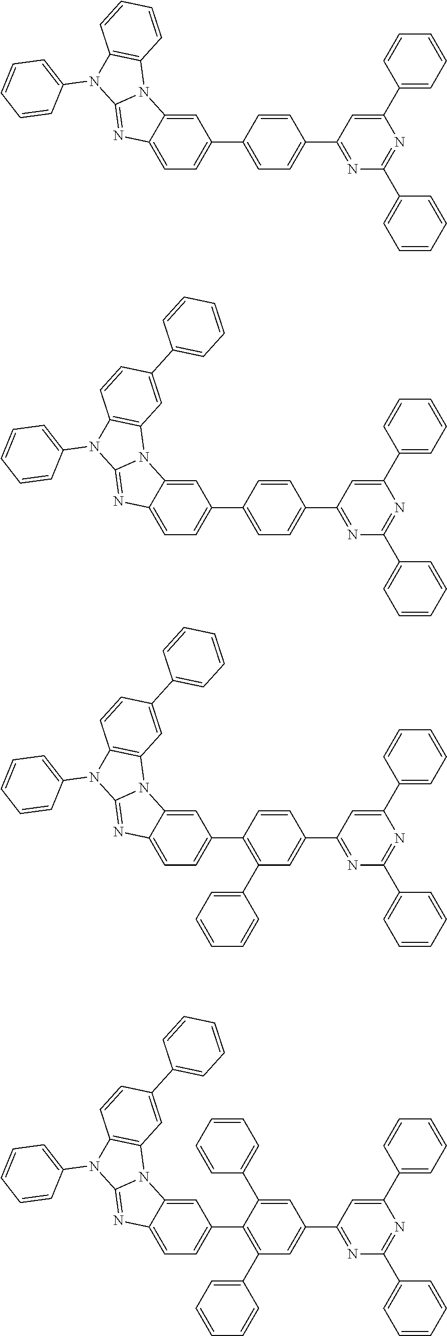 [SMILES: c1ccc(-c2cc(-c3ccc(-c4ccc5nc6n(-c7ccccc7)c7ccccc7n6c5c4)cc3)nc(-c3ccccc3)n2)cc1 ; c1ccc(-c2ccc3c(c2)n2c4cc(-c5ccc(-c6cc(-c7ccccc7)nc(-c7ccccc7)n6)cc5)ccc4nc2n3-c2ccccc2)cc1 ; c1ccc(-c2ccc3c(c2)n2c4cc(-c5ccc(-c6cc(-c7ccccc7)nc(-c7ccccc7)n6)cc5-c5ccccc5)ccc4nc2n3-c2ccccc2)cc1 ; c1ccc(-c2ccc3c(c2)n2c4cc(-c5c(-c6ccccc6)cc(-c6cc(-c7ccccc7)nc(-c7ccccc7)n6)cc5-c5ccccc5)ccc4nc2n3-c2ccccc2)cc1]

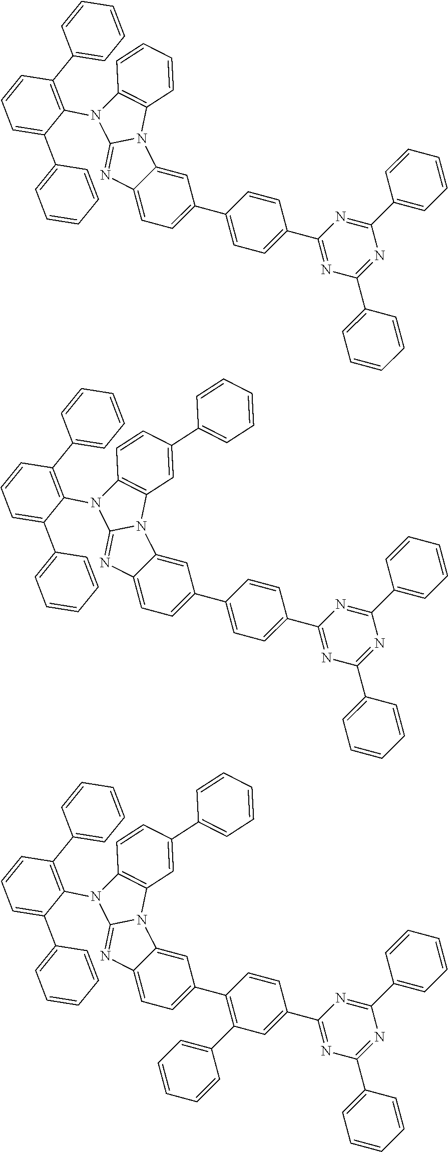 [SMILES: c1ccc(-c2nc(-c3ccccc3)nc(-c3ccc(-c4ccc5nc6n(-c7c(-c8ccccc8)cccc7-c7ccccc7)c7ccccc7n6c5c4)cc3)n2)cc1 ; c1ccc(-c2ccc3c(c2)n2c4cc(-c5ccc(-c6nc(-c7ccccc7)nc(-c7ccccc7)n6)cc5)ccc4nc2n3-c2c(-c3ccccc3)cccc2-c2ccccc2)cc1 ; c1ccc(-c2ccc3c(c2)n2c4cc(-c5ccc(-c6nc(-c7ccccc7)nc(-c7ccccc7)n6)cc5-c5ccccc5)ccc4nc2n3-c2c(-c3ccccc3)cccc2-c2ccccc2)cc1]

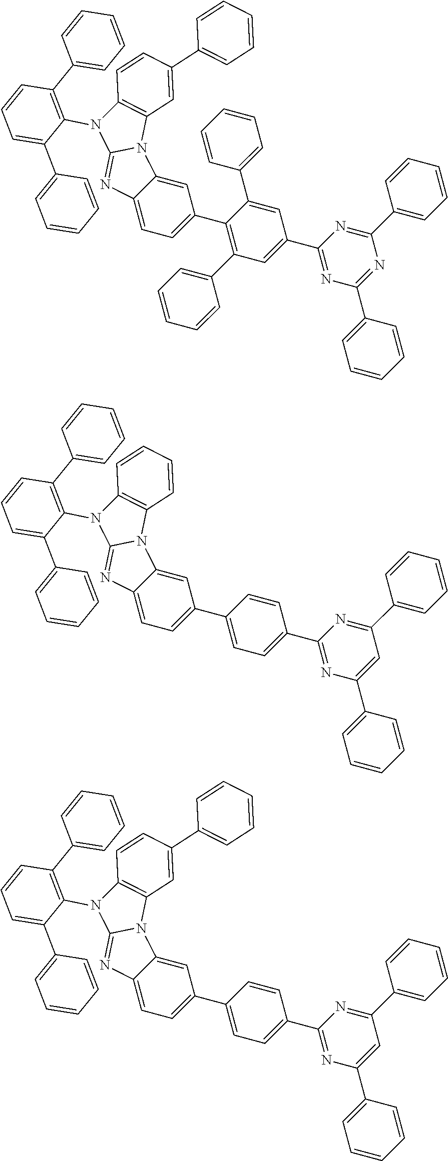 [SMILES: c1ccc(-c2ccc3c(c2)n2c4cc(-c5c(-c6ccccc6)cc(-c6nc(-c7ccccc7)nc(-c7ccccc7)n6)cc5-c5ccccc5)ccc4nc2n3-c2c(-c3ccccc3)cccc2-c2ccccc2)cc1 ; c1ccc(-c2cc(-c3ccccc3)nc(-c3ccc(-c4ccc5nc6n(-c7c(-c8ccccc8)cccc7-c7ccccc7)c7ccccc7n6c5c4)cc3)n2)cc1 ; c1ccc(-c2ccc3c(c2)n2c4cc(-c5ccc(-c6nc(-c7ccccc7)cc(-c7ccccc7)n6)cc5)ccc4nc2n3-c2c(-c3ccccc3)cccc2-c2ccccc2)cc1]

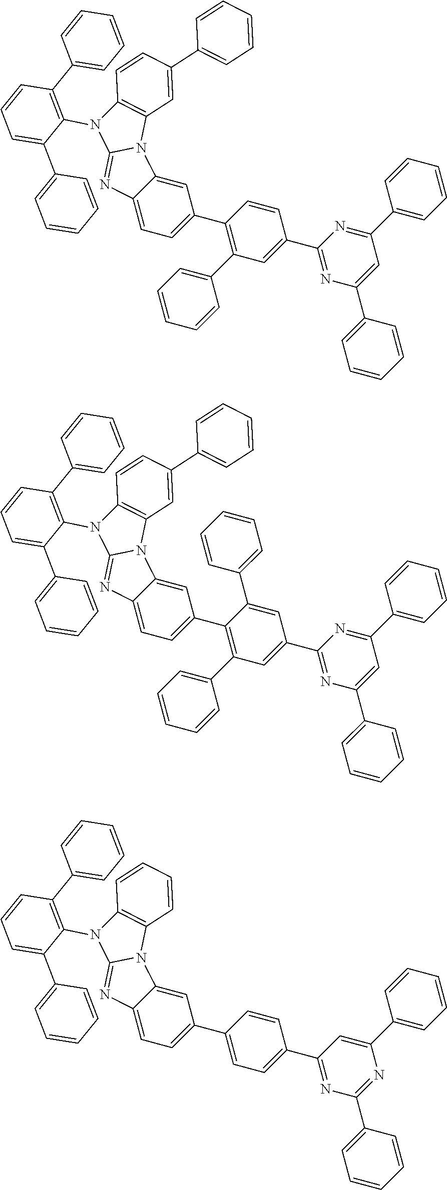 [SMILES: c1ccc(-c2ccc3c(c2)n2c4cc(-c5ccc(-c6nc(-c7ccccc7)cc(-c7ccccc7)n6)cc5-c5ccccc5)ccc4nc2n3-c2c(-c3ccccc3)cccc2-c2ccccc2)cc1 ; c1ccc(-c2ccc3c(c2)n2c4cc(-c5c(-c6ccccc6)cc(-c6nc(-c7ccccc7)cc(-c7ccccc7)n6)cc5-c5ccccc5)ccc4nc2n3-c2c(-c3ccccc3)cccc2-c2ccccc2)cc1 ; c1ccc(-c2cc(-c3ccc(-c4ccc5nc6n(-c7c(-c8ccccc8)cccc7-c7ccccc7)c7ccccc7n6c5c4)cc3)nc(-c3ccccc3)n2)cc1]

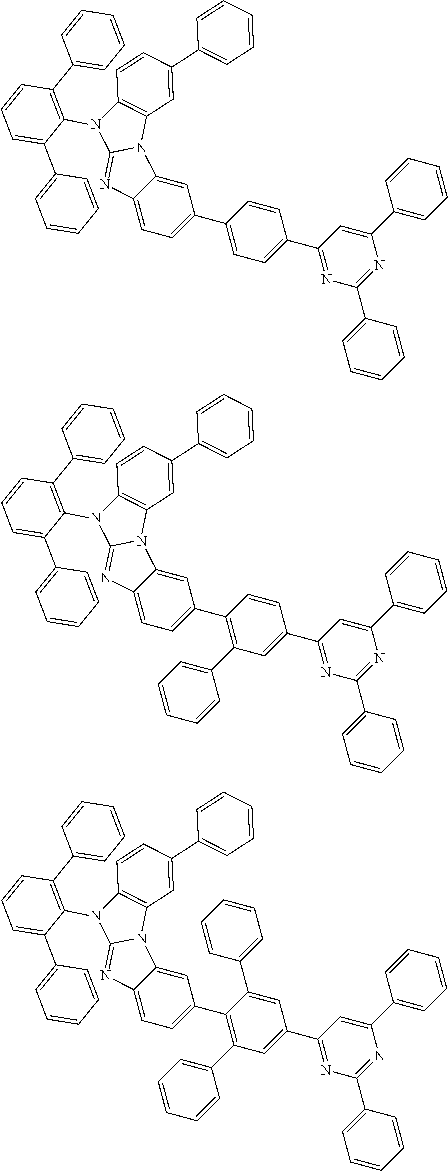 [SMILES: c1ccc(-c2ccc3c(c2)n2c4cc(-c5ccc(-c6cc(-c7ccccc7)nc(-c7ccccc7)n6)cc5)ccc4nc2n3-c2c(-c3ccccc3)cccc2-c2ccccc2)cc1 ; c1ccc(-c2ccc3c(c2)n2c4cc(-c5ccc(-c6cc(-c7ccccc7)nc(-c7ccccc7)n6)cc5-c5ccccc5)ccc4nc2n3-c2c(-c3ccccc3)cccc2-c2ccccc2)cc1 ; c1ccc(-c2ccc3c(c2)n2c4cc(-c5c(-c6ccccc6)cc(-c6cc(-c7ccccc7)nc(-c7ccccc7)n6)cc5-c5ccccc5)ccc4nc2n3-c2c(-c3ccccc3)cccc2-c2ccccc2)cc1]

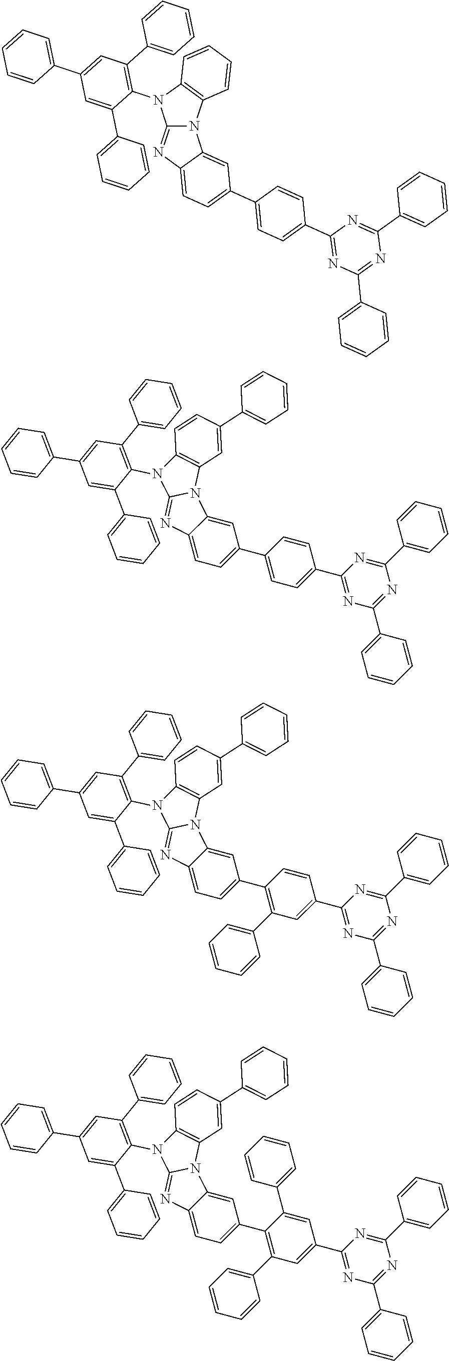

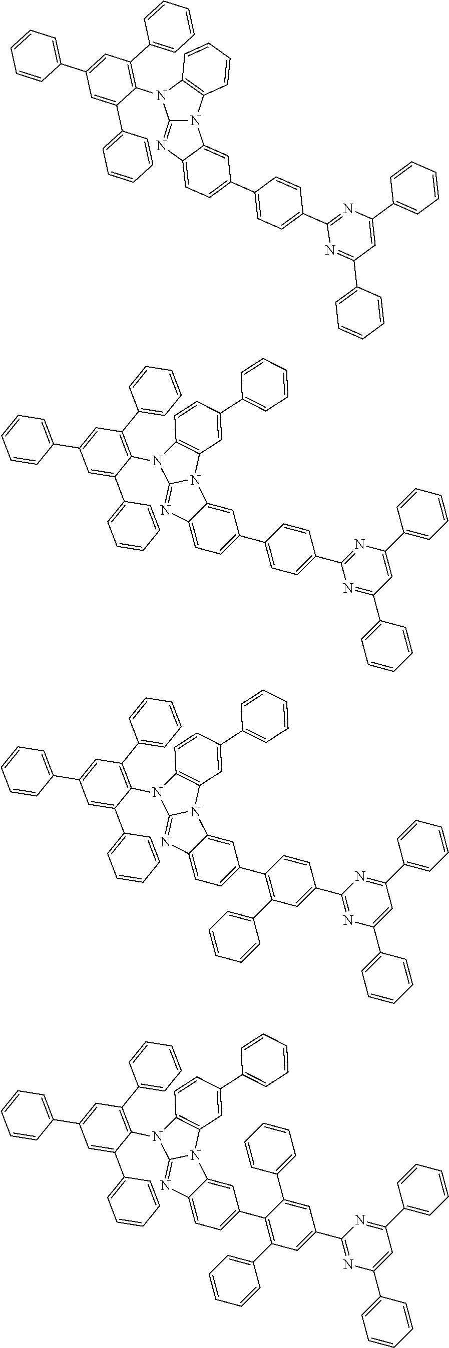

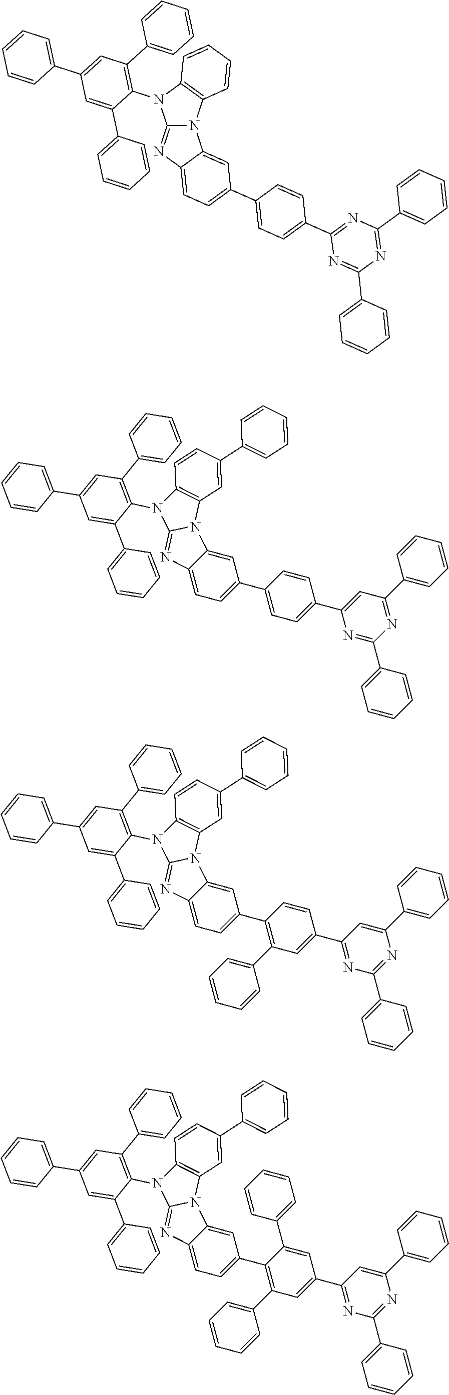

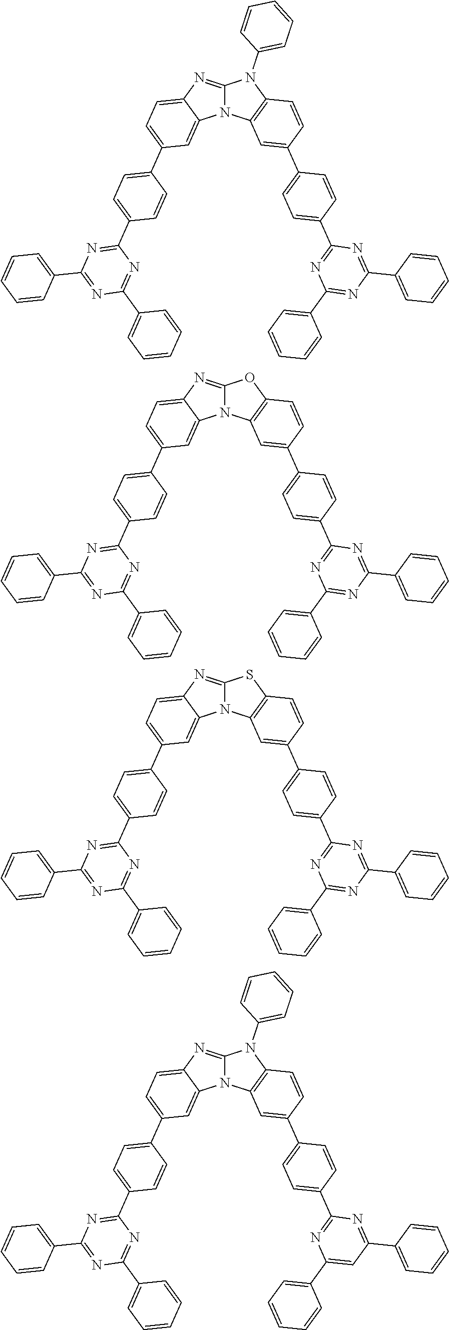

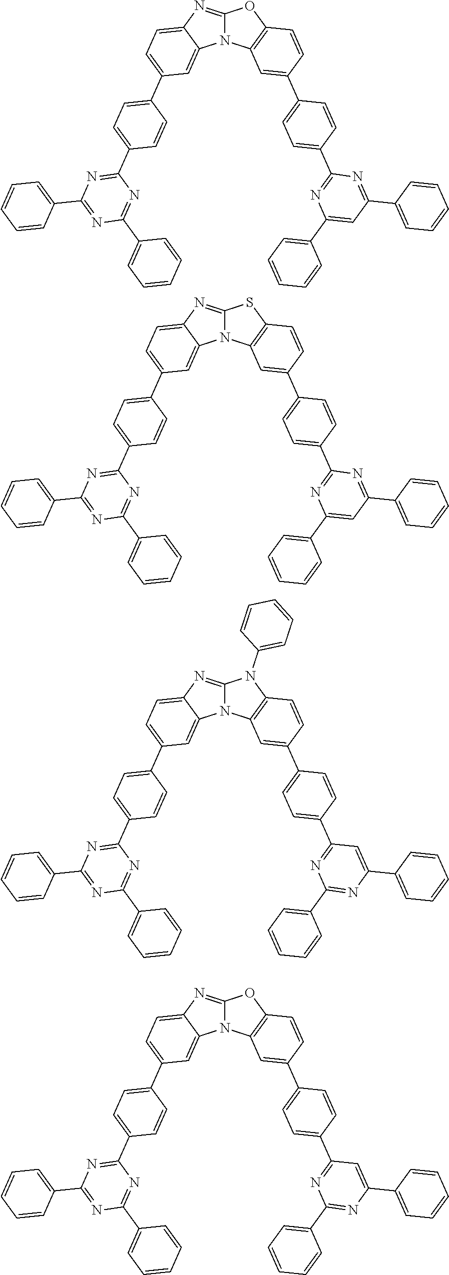

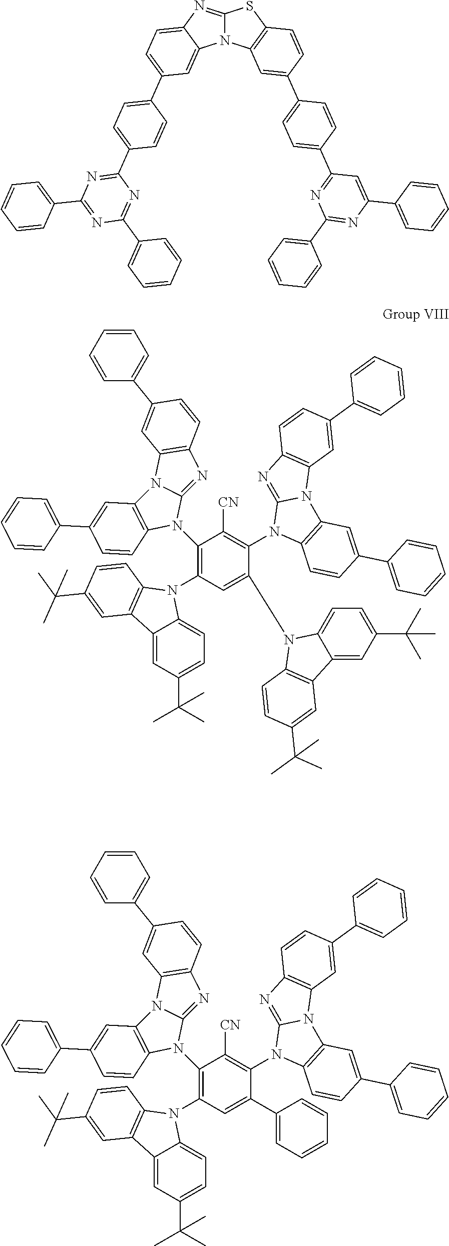 [SMILES: c1ccc(-c2cc(-c3ccc(-c4ccc5sc6nc7ccc(-c8ccc(-c9nc(-c%10ccccc%10)nc(-c%10ccccc%10)n9)cc8)cc7n6c5c4)cc3)nc(-c3ccccc3)n2)cc1 ; CC(C)(C)c1ccc2c(c1)c1cc(C(C)(C)C)ccc1n2-c1cc(-n2c3ccc(C(C)(C)C)cc3c3cc(C(C)(C)C)ccc32)c(-n2c3ccc(-c4ccccc4)cc3n3c4cc(-c5ccccc5)ccc4nc23)c(C#N)c1-n1c2ccc(-c3ccccc3)cc2n2c3cc(-c4ccccc4)ccc3nc12 ; CC(C)(C)c1ccc2c(c1)c1cc(C(C)(C)C)ccc1n2-c1cc(-c2ccccc2)c(-n2c3ccc(-c4ccccc4)cc3n3c4cc(-c5ccccc5)ccc4nc23)c(C#N)c1-n1c2ccc(-c3ccccc3)cc2n2c3cc(-c4ccccc4)ccc3nc12]

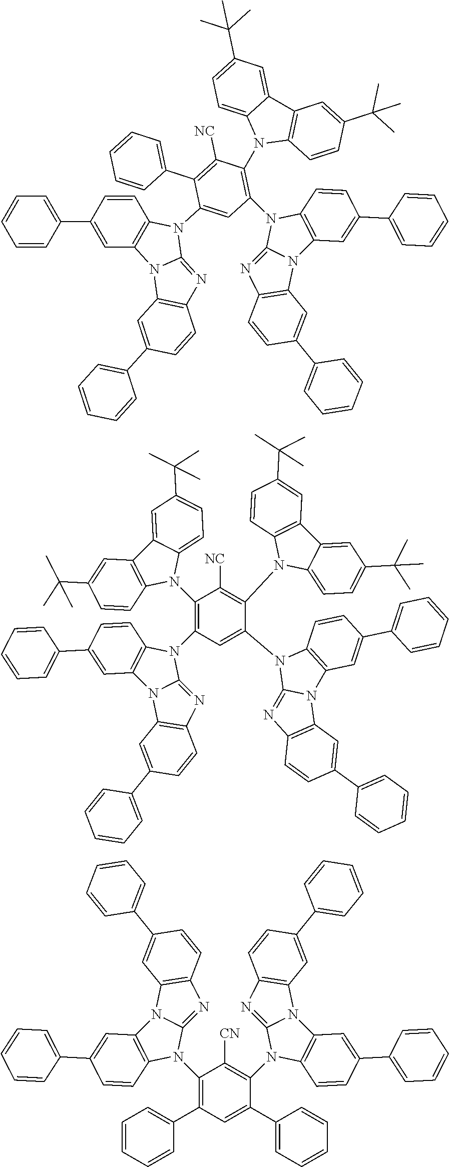

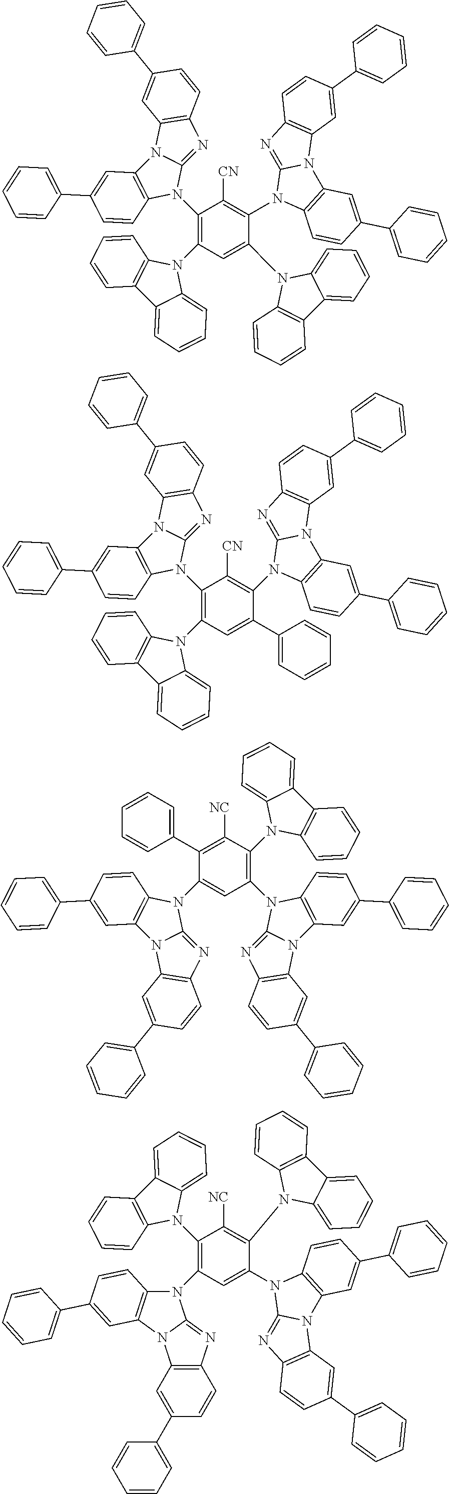

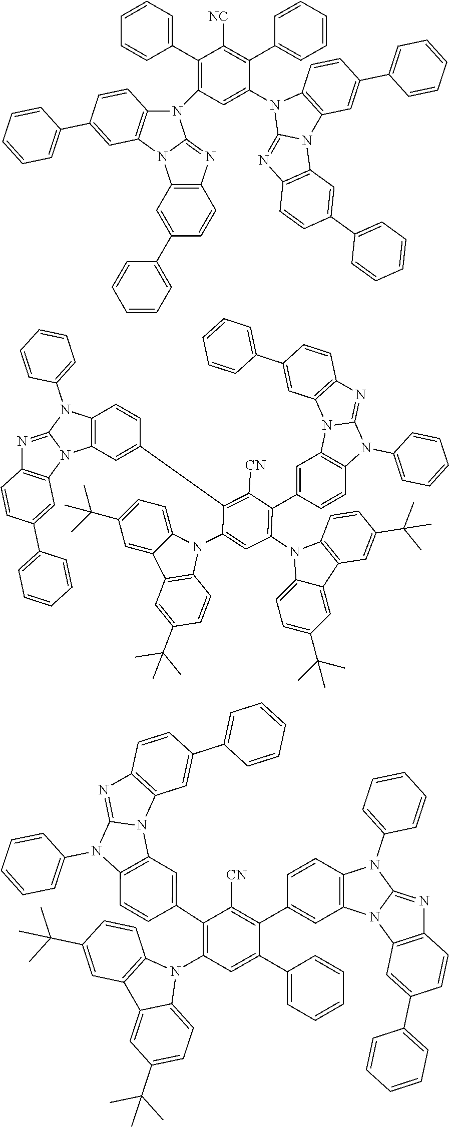 [SMILES: N#Cc1c(-c2ccccc2)c(-n2c3ccc(-c4ccccc4)cc3n3c4cc(-c5ccccc5)ccc4nc23)cc(-n2c3ccc(-c4ccccc4)cc3n3c4cc(-c5ccccc5)ccc4nc23)c1-c1ccccc1 ; CC(C)(C)c1ccc2c(c1)c1cc(C(C)(C)C)ccc1n2-c1cc(-n2c3ccc(C(C)(C)C)cc3c3cc(C(C)(C)C)ccc32)c(-c2ccc3c(c2)n2c4cc(-c5ccccc5)ccc4nc2n3-c2ccccc2)c(C#N)c1-c1ccc2c(c1)n1c3cc(-c4ccccc4)ccc3nc1n2-c1ccccc1 ; CC(C)(C)c1ccc2c(c1)c1cc(C(C)(C)C)ccc1n2-c1cc(-c2ccccc2)c(-c2ccc3c(c2)n2c4cc(-c5ccccc5)ccc4nc2n3-c2ccccc2)c(C#N)c1-c1ccc2c(c1)n1c3cc(-c4ccccc4)ccc3nc1n2-c1ccccc1]

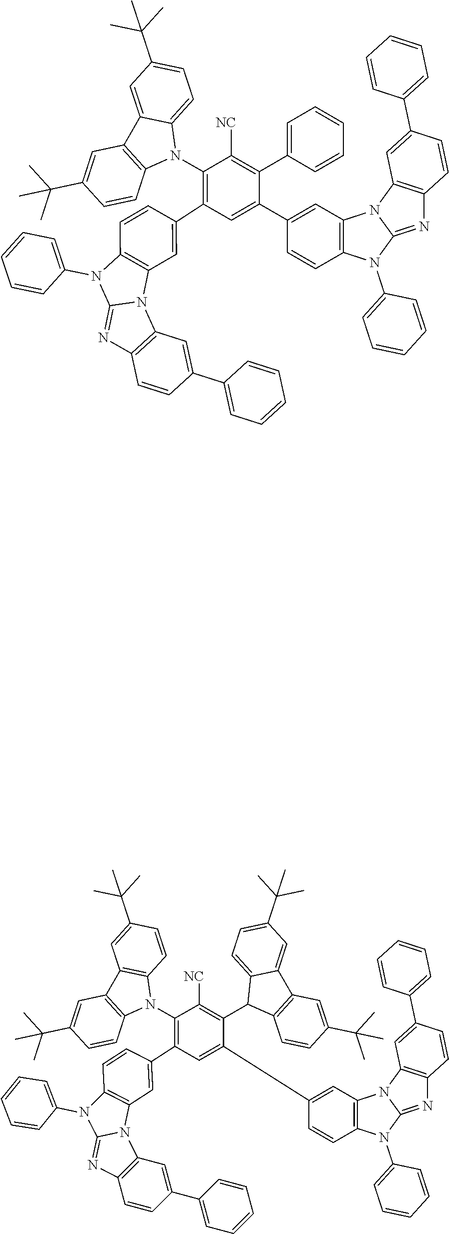 [SMILES: CC(C)(C)c1ccc2c(c1)c1cc(C(C)(C)C)ccc1n2-c1c(-c2ccc3c(c2)n2c4cc(-c5ccccc5)ccc4nc2n3-c2ccccc2)cc(-c2ccc3c(c2)n2c4cc(-c5ccccc5)ccc4nc2n3-c2ccccc2)c(-c2ccccc2)c1C#N ; CC(C)(C)c1ccc2c(c1)-c1cc(C(C)(C)C)ccc1C2c1c(-c2ccc3c(c2)n2c4cc(-c5ccccc5)ccc4nc2n3-c2ccccc2)cc(-c2ccc3c(c2)n2c4cc(-c5ccccc5)ccc4nc2n3-c2ccccc2)c(-n2c3ccc(C(C)(C)C)cc3c3cc(C(C)(C)C)ccc32)c1C#N]

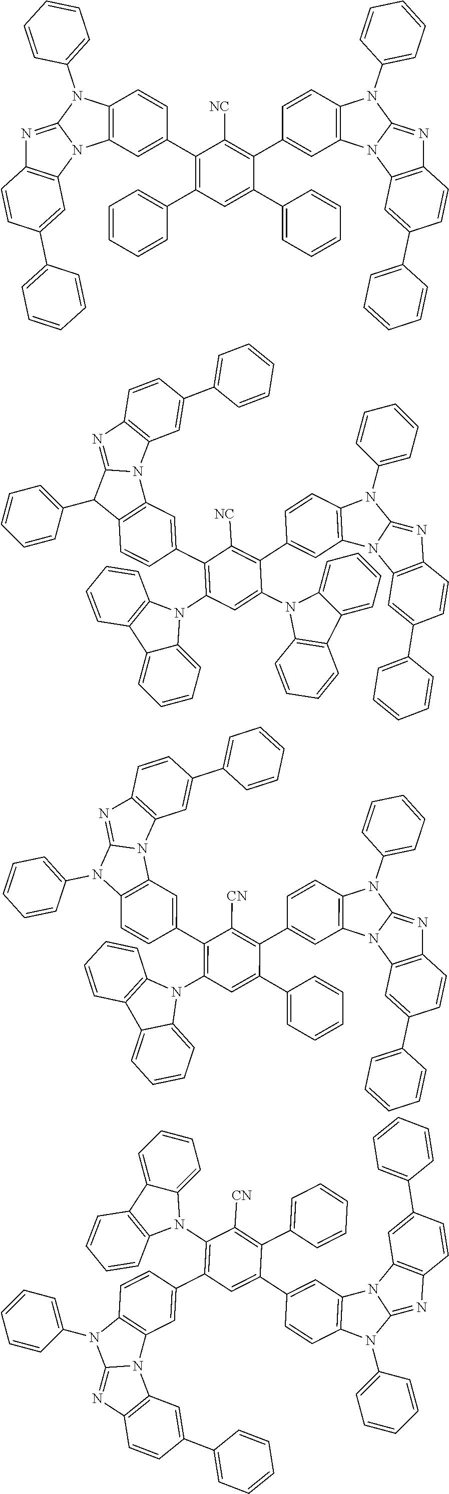

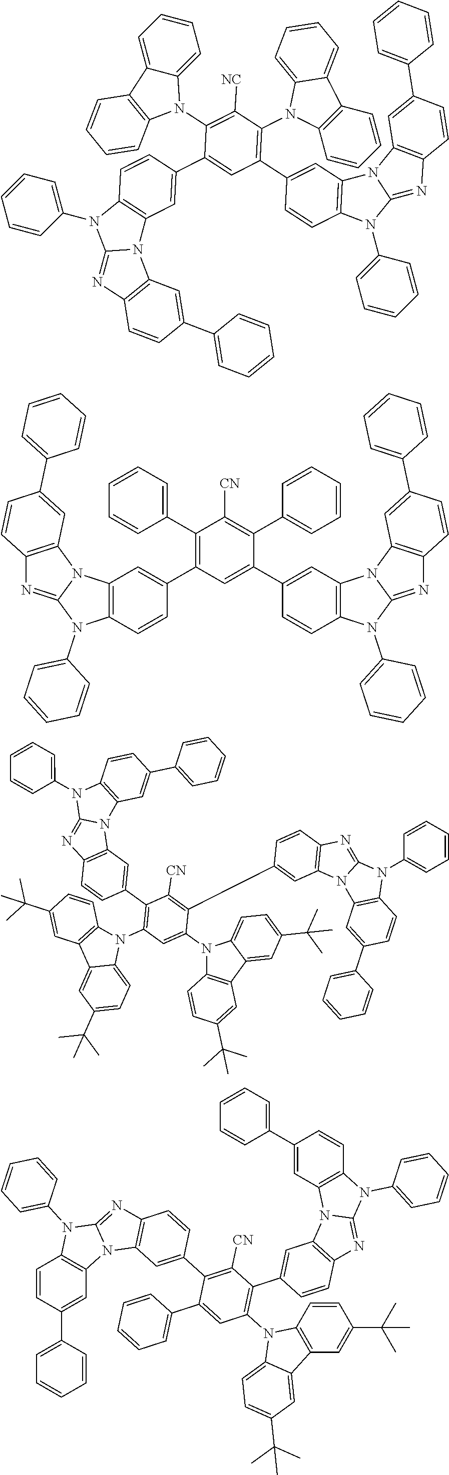

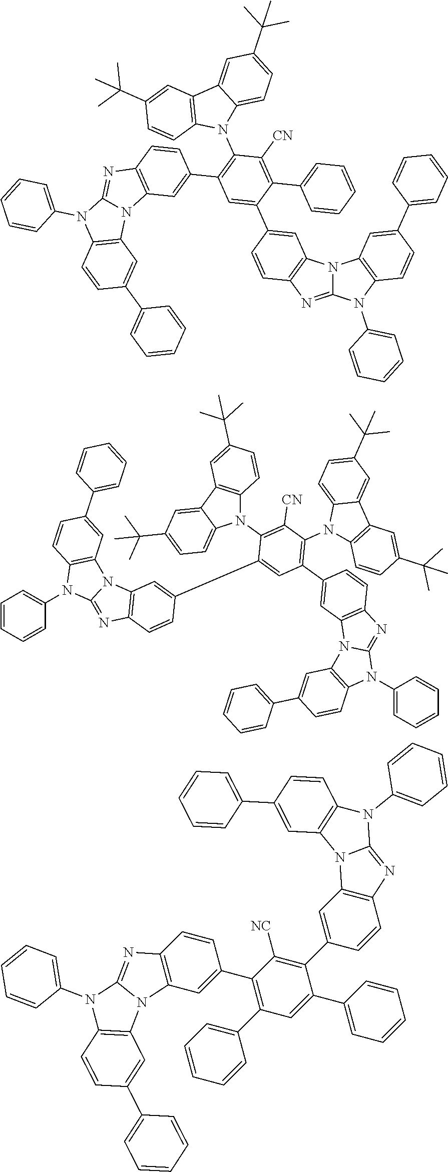

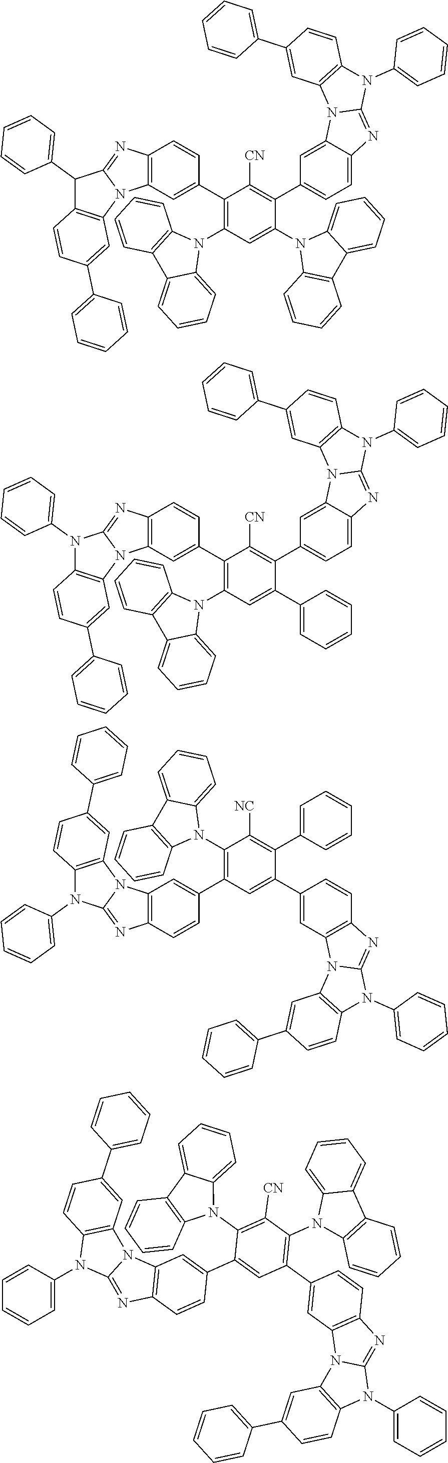

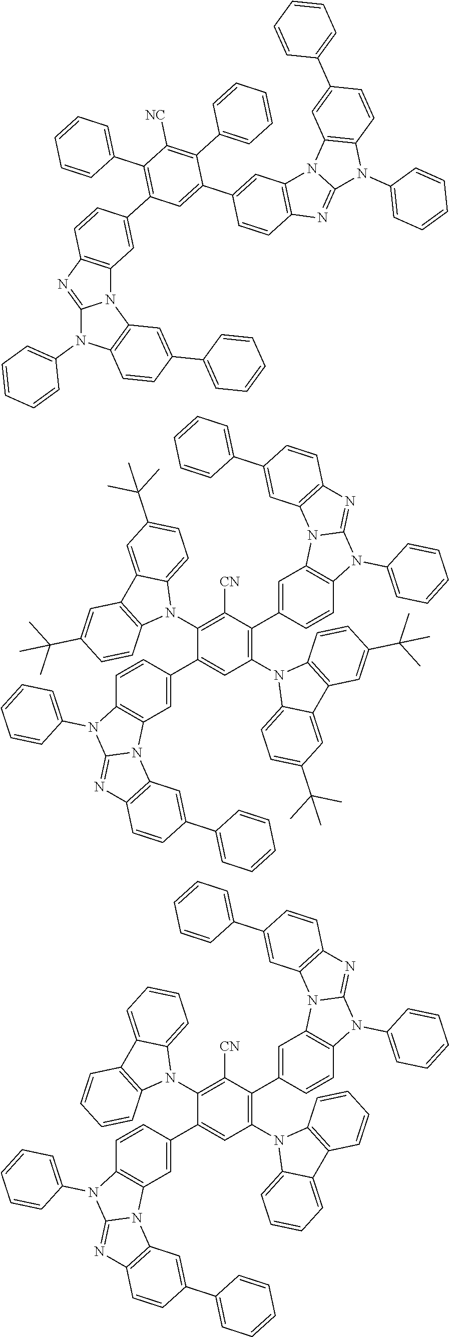

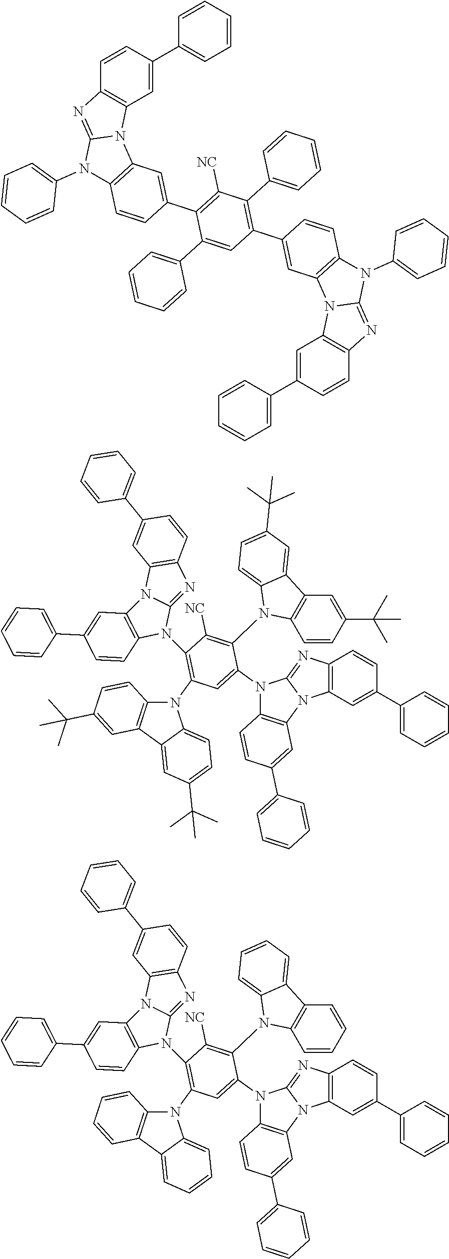 [SMILES: N#Cc1c(-c2ccccc2)c(-c2ccc3c(c2)n2c4cc(-c5ccccc5)ccc4nc2n3-c2ccccc2)cc(-c2ccccc2)c1-c1ccc2c(c1)n1c3cc(-c4ccccc4)ccc3nc1n2-c1ccccc1 ; CC(C)(C)c1ccc2c(c1)c1cc(C(C)(C)C)ccc1n2-c1cc(-n2c3ccc(-c4ccccc4)cc3n3c4cc(-c5ccccc5)ccc4nc23)c(-n2c3ccc(C(C)(C)C)cc3c3cc(C(C)(C)C)ccc32)c(C#N)c1-n1c2ccc(-c3ccccc3)cc2n2c3cc(-c4ccccc4)ccc3nc12 ; N#Cc1c(-n2c3ccccc3c3ccccc32)c(-n2c3ccc(-c4ccccc4)cc3n3c4cc(-c5ccccc5)ccc4nc23)cc(-n2c3ccccc3c3ccccc32)c1-n1c2ccc(-c3ccccc3)cc2n2c3cc(-c4ccccc4)ccc3nc12]

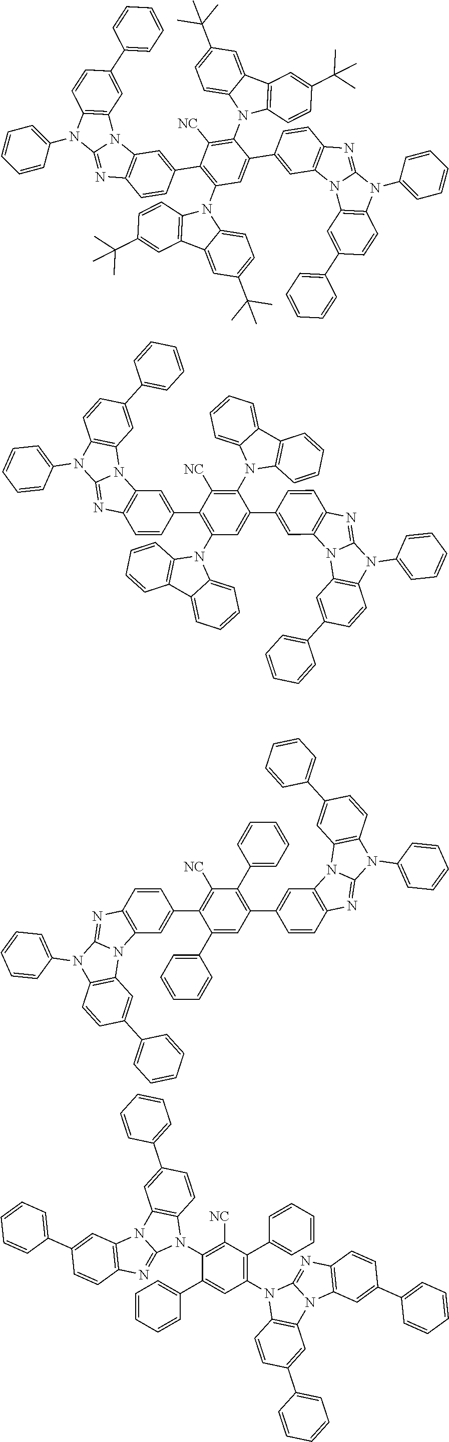

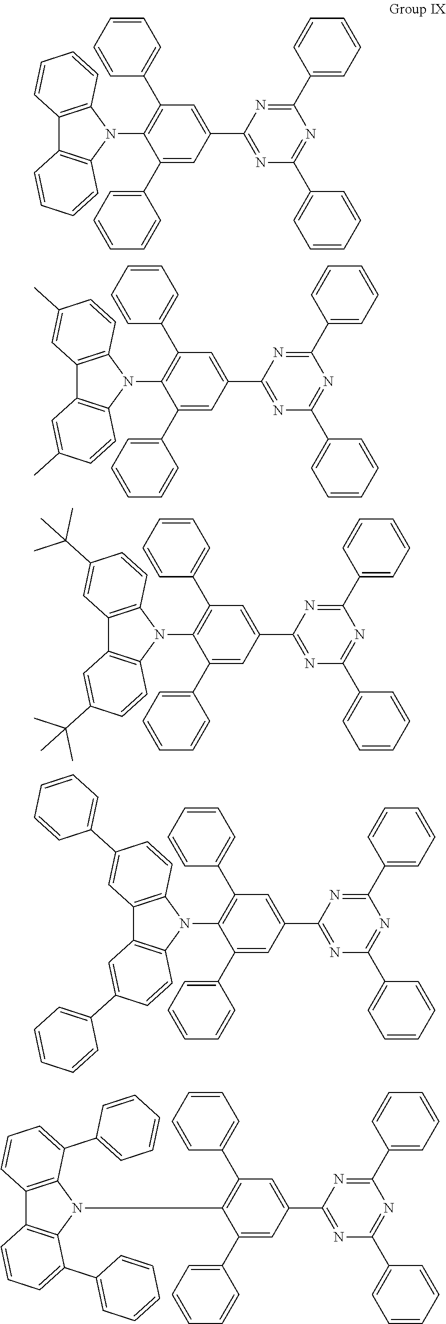

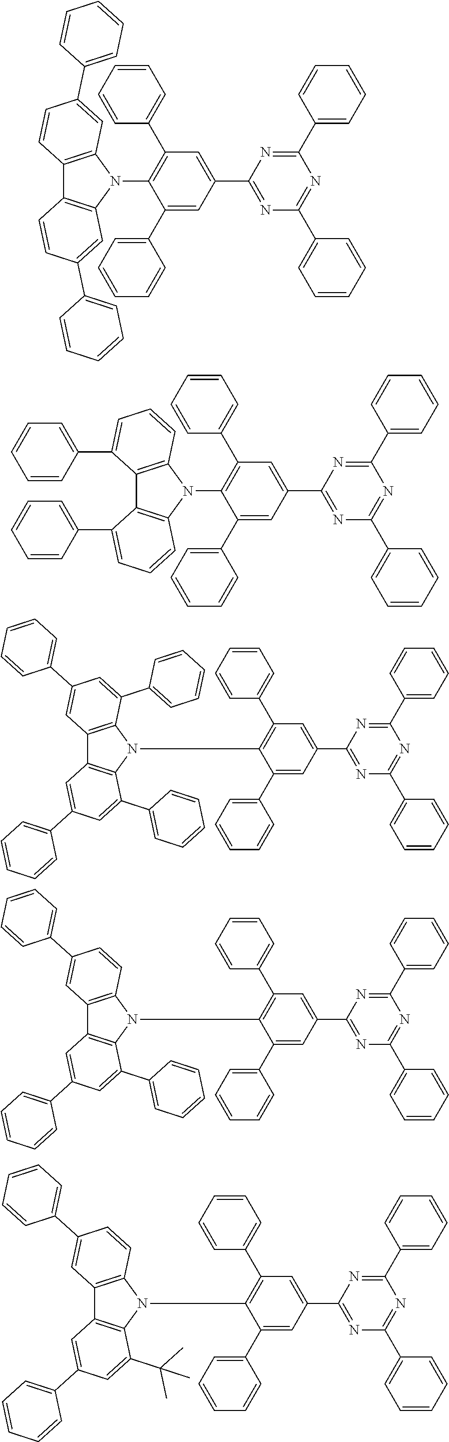

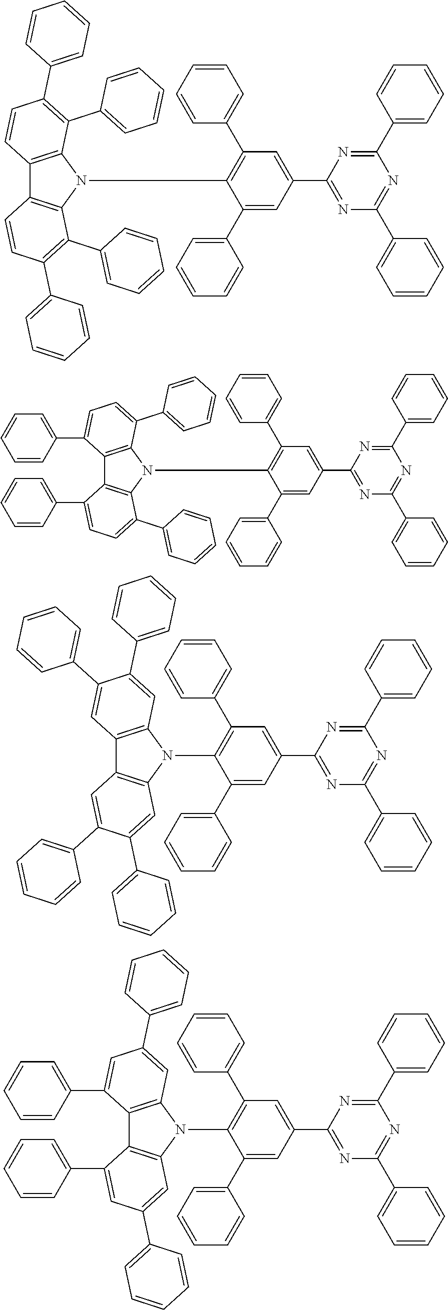

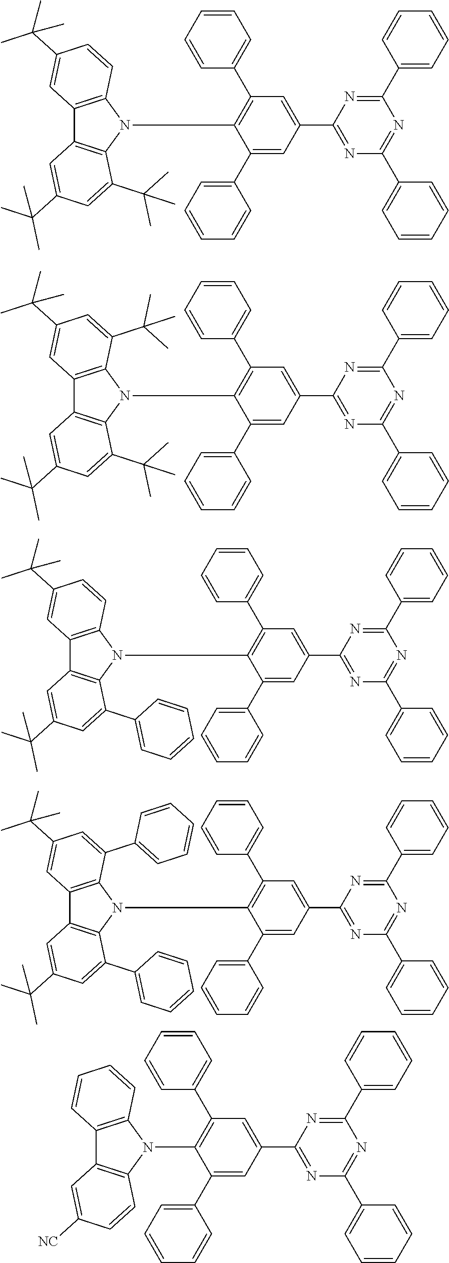

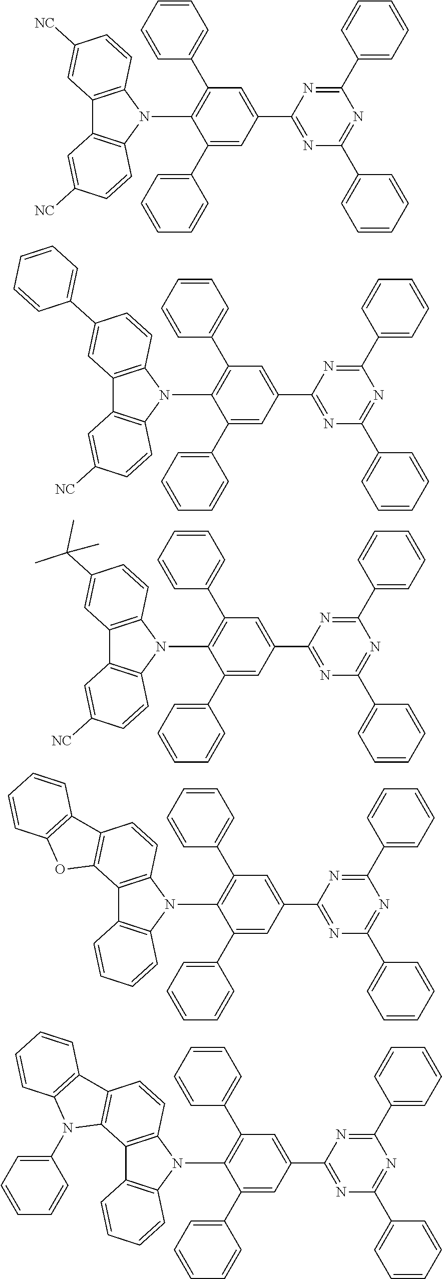

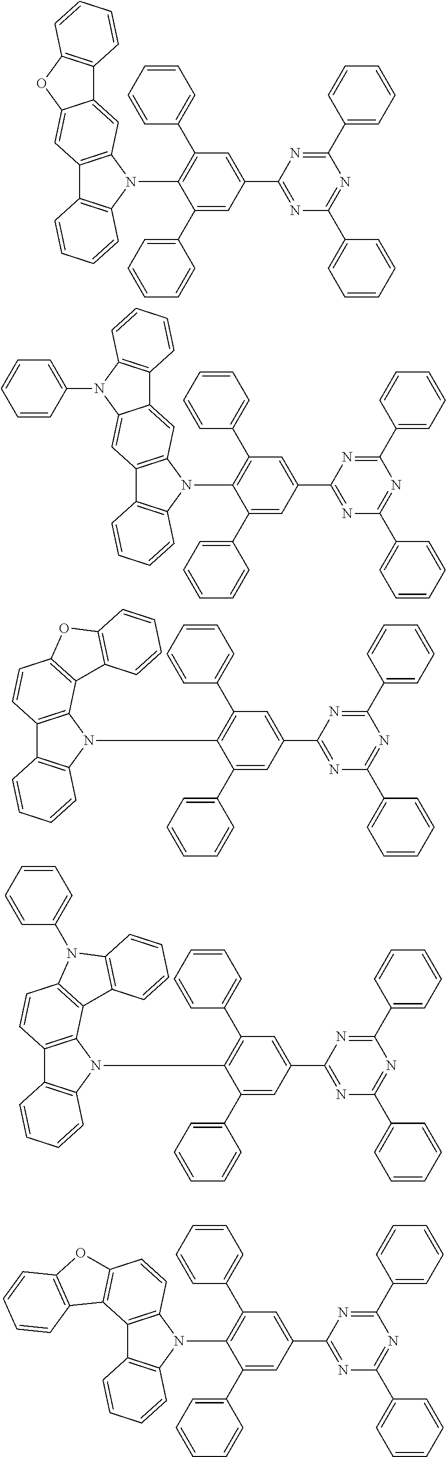

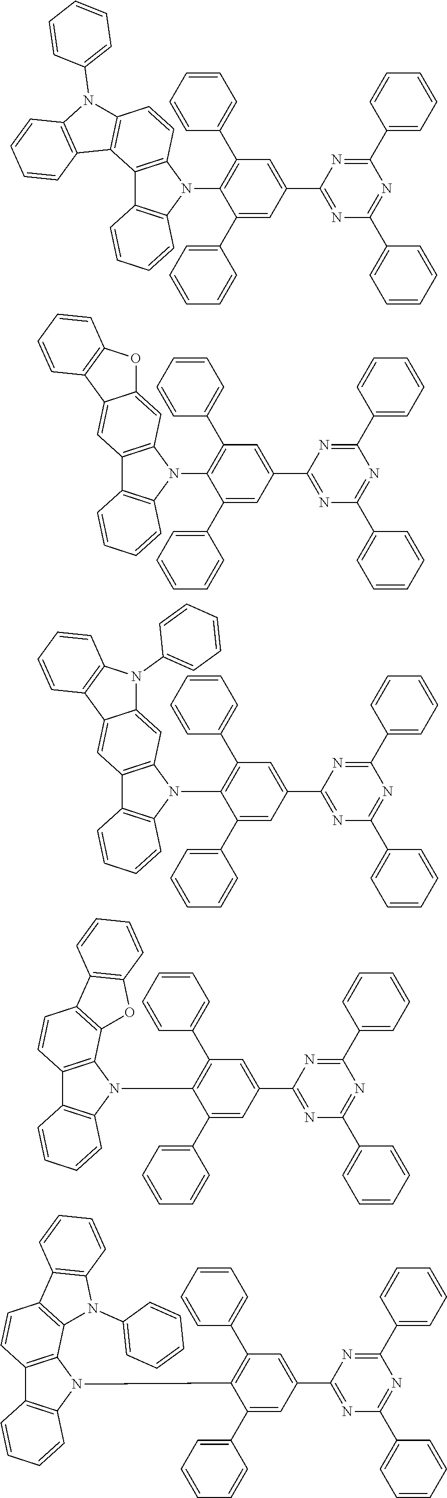

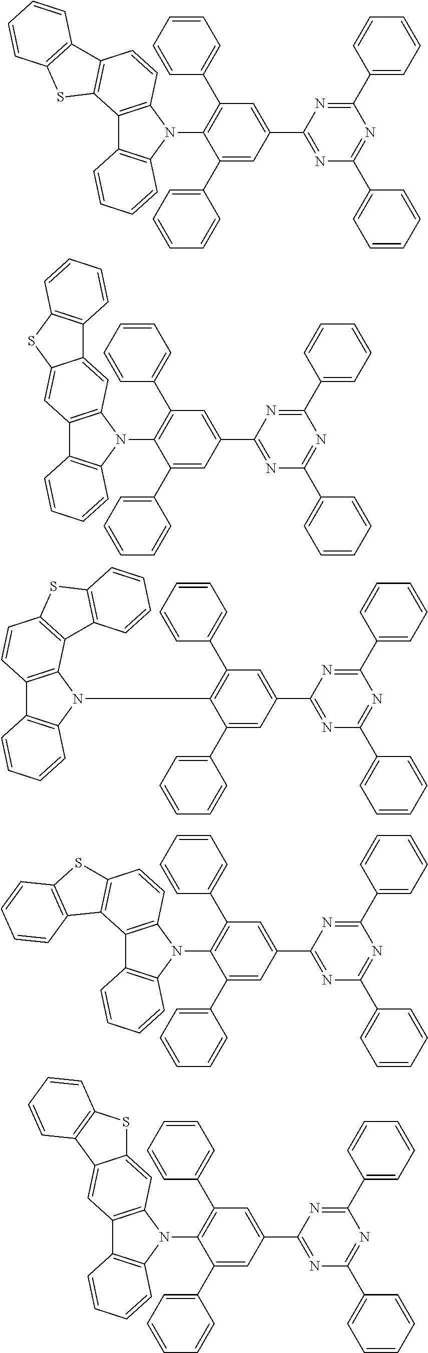

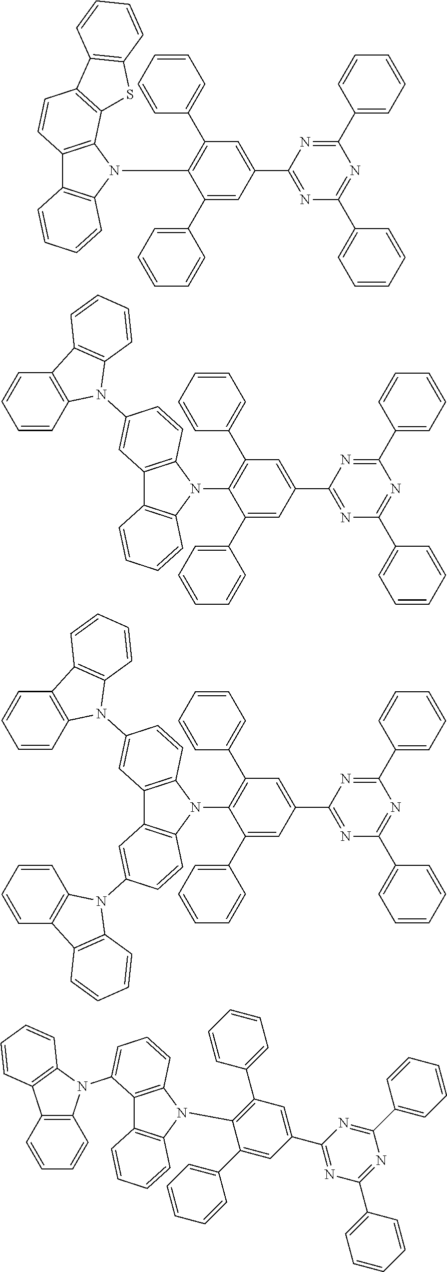

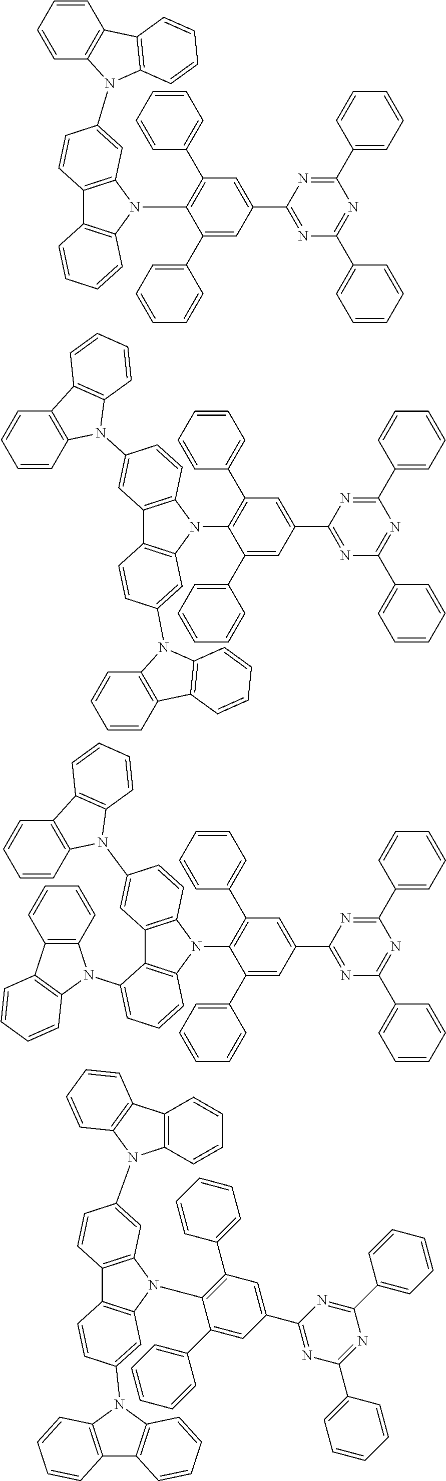

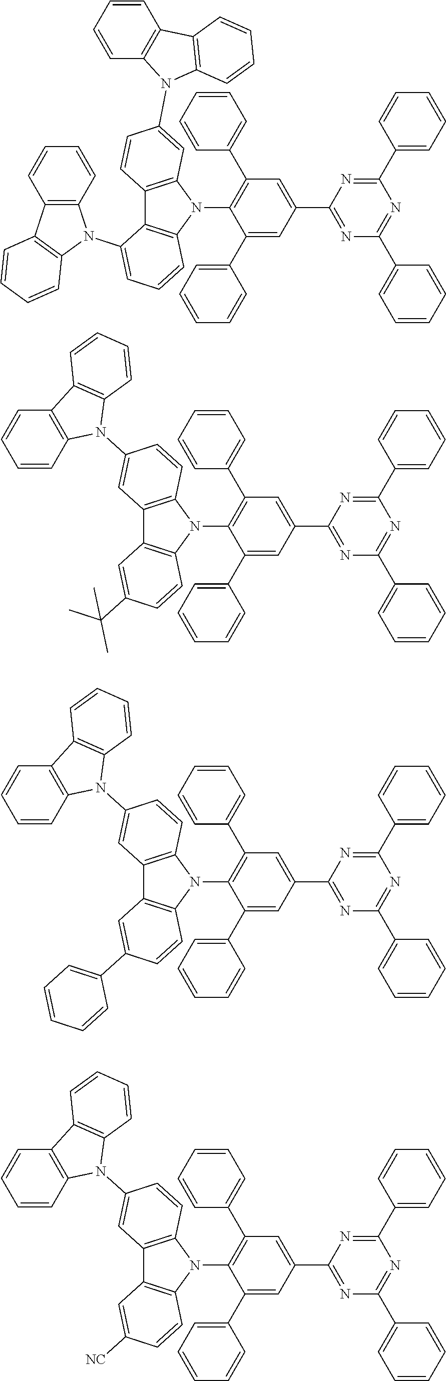

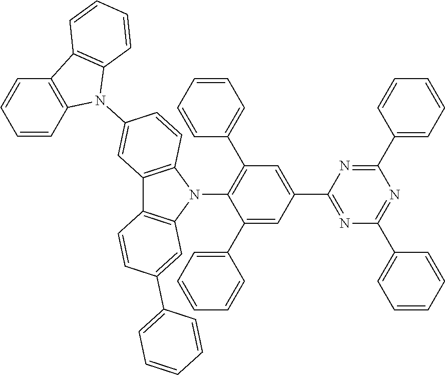 [SMILES: c1ccc(-c2ccc3c4cc(-n5c6ccccc6c6ccccc65)ccc4n(-c4c(-c5ccccc5)cc(-c5nc(-c6ccccc6)nc(-c6ccccc6)n5)cc4-c4ccccc4)c3c2)cc1]

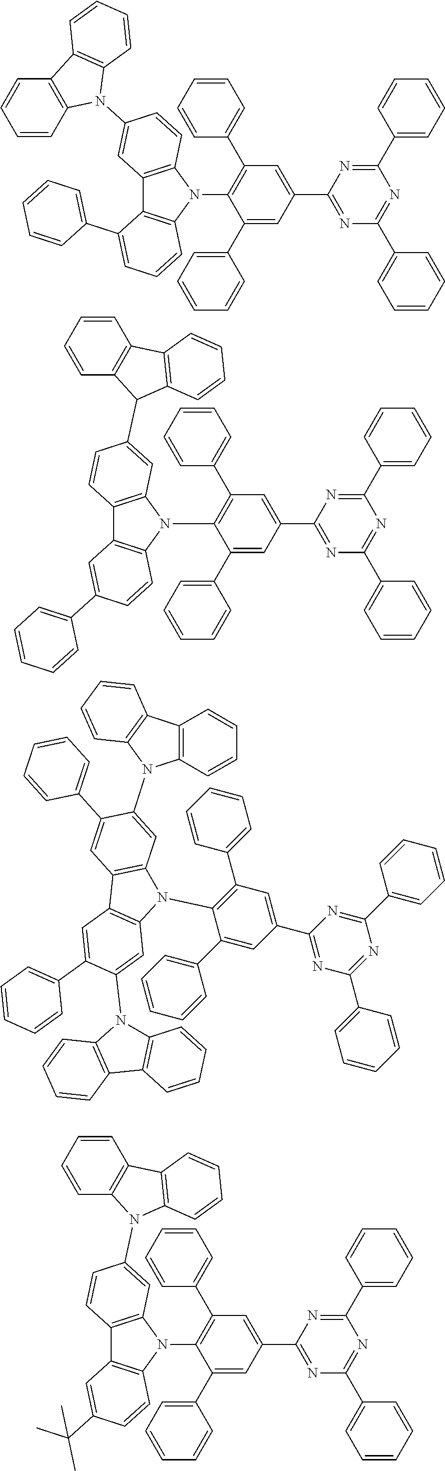

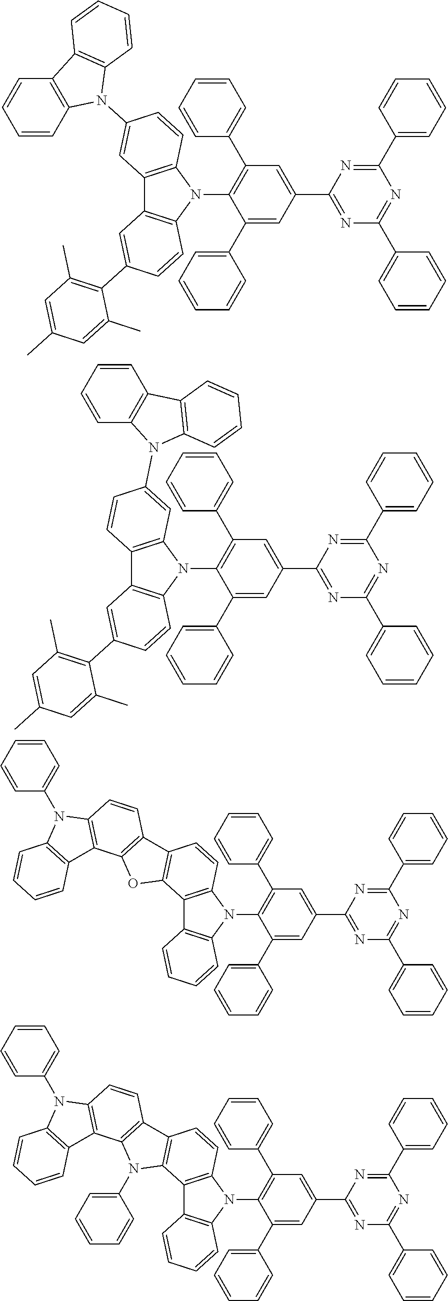

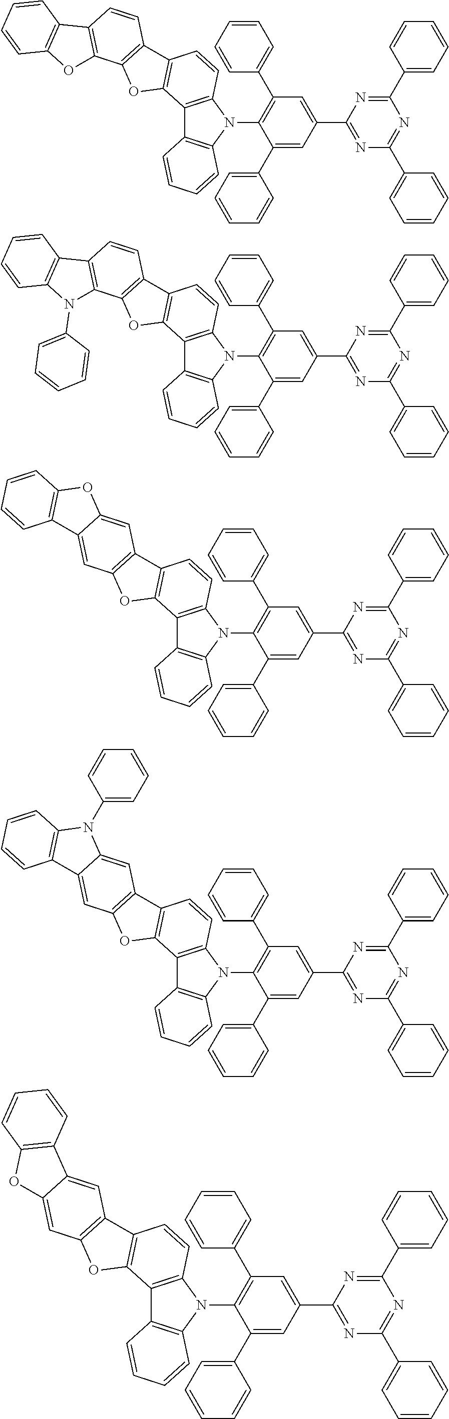

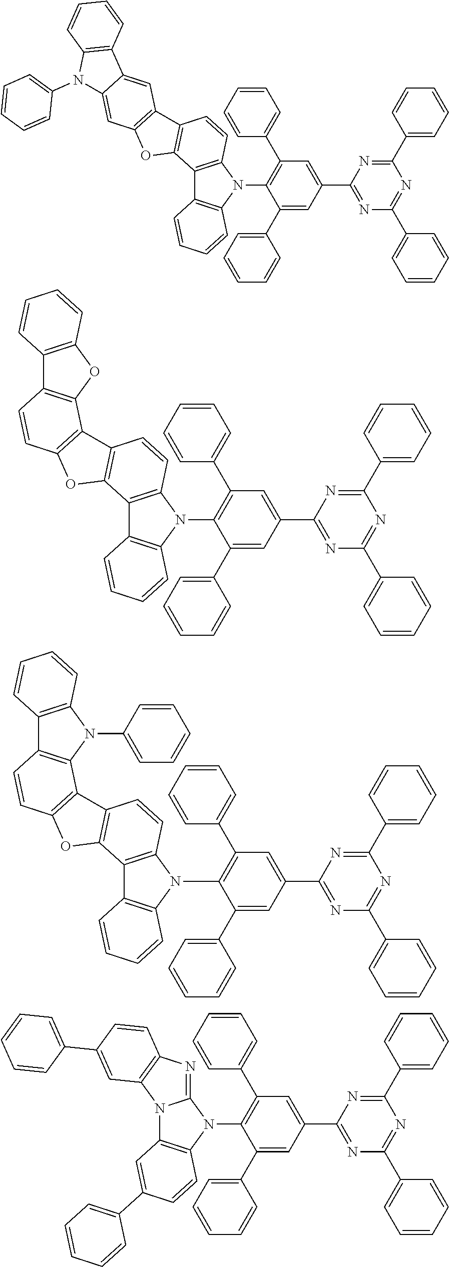

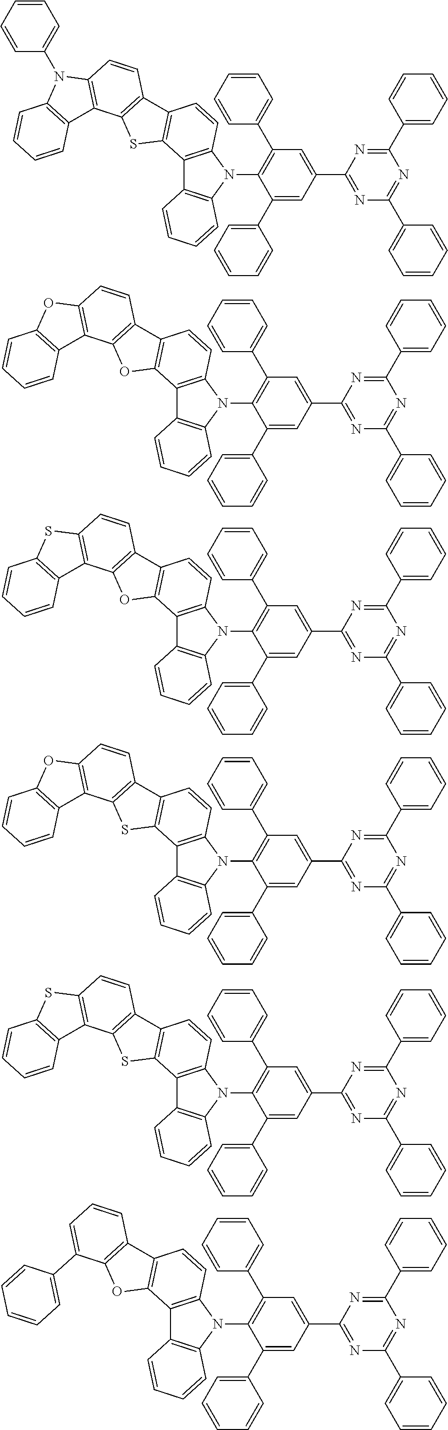

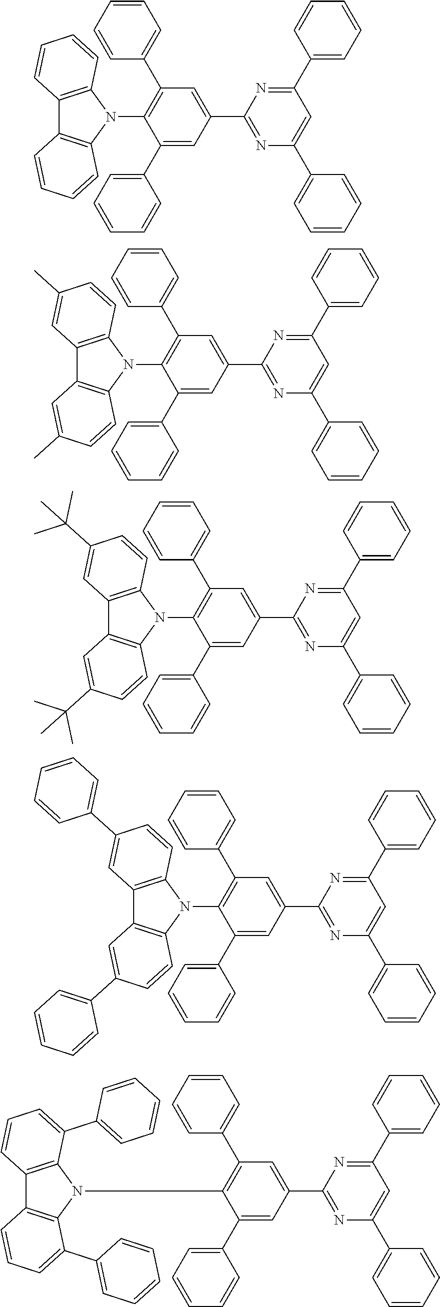

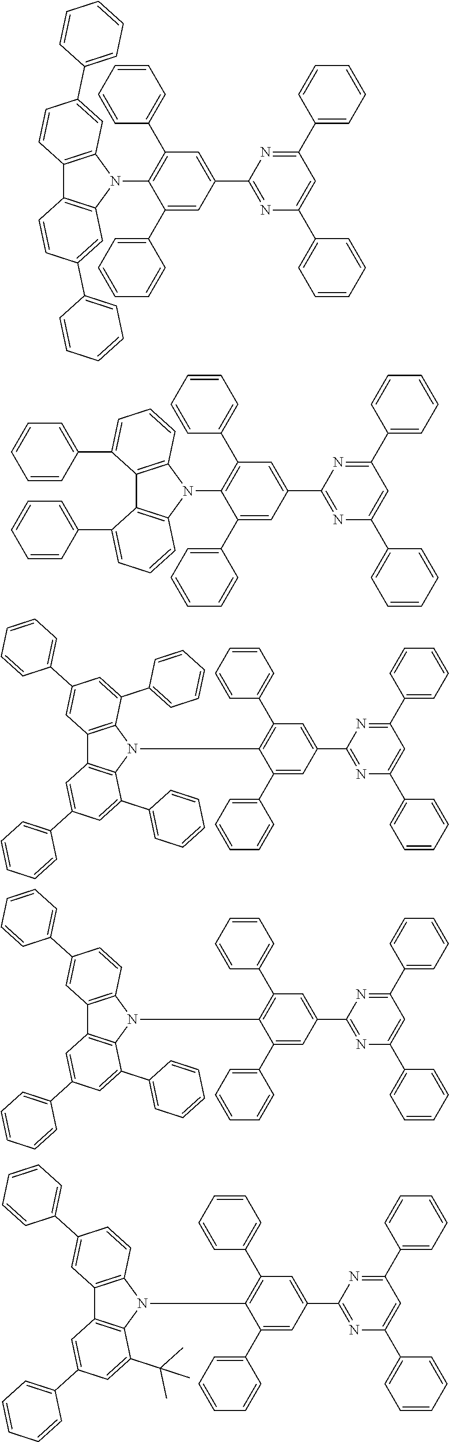

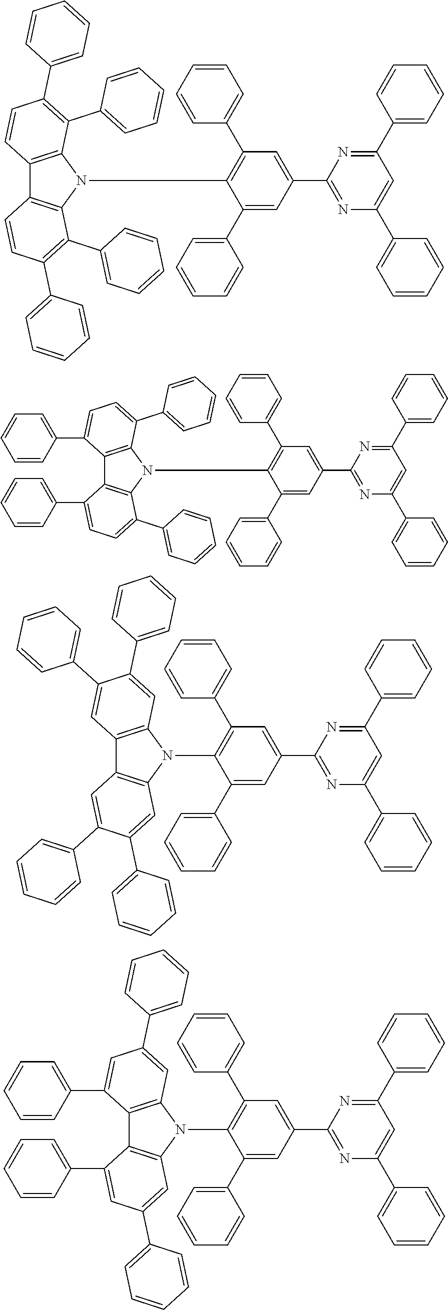

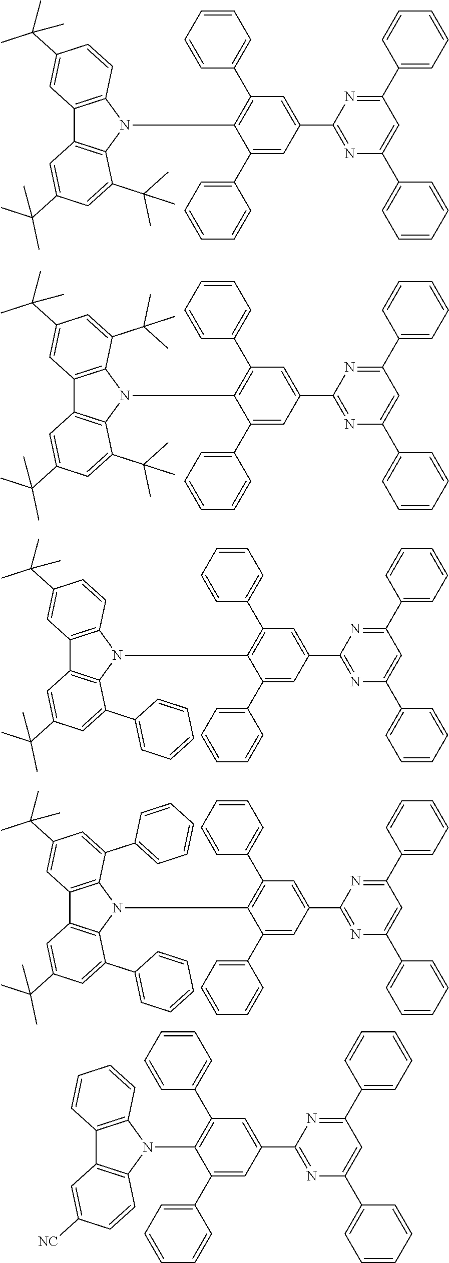

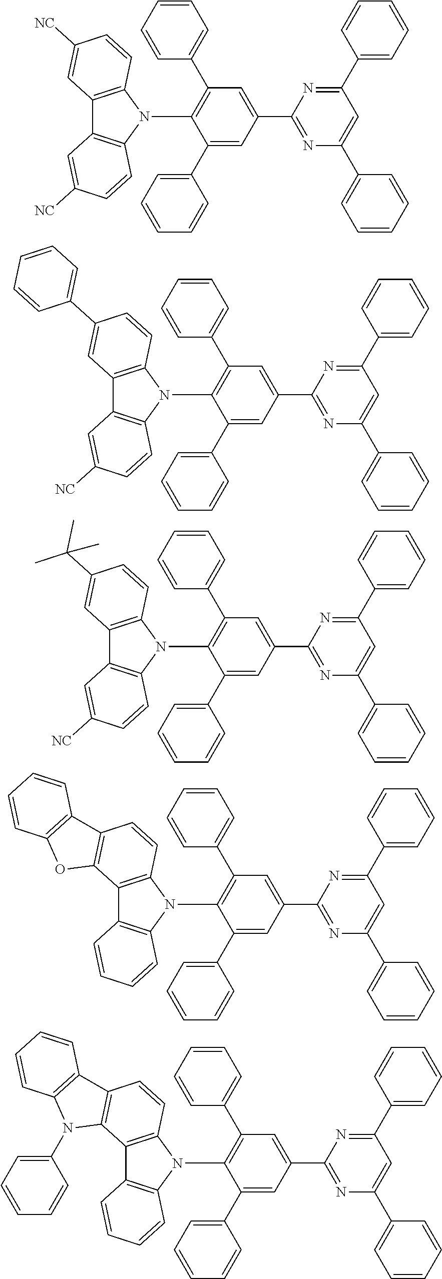

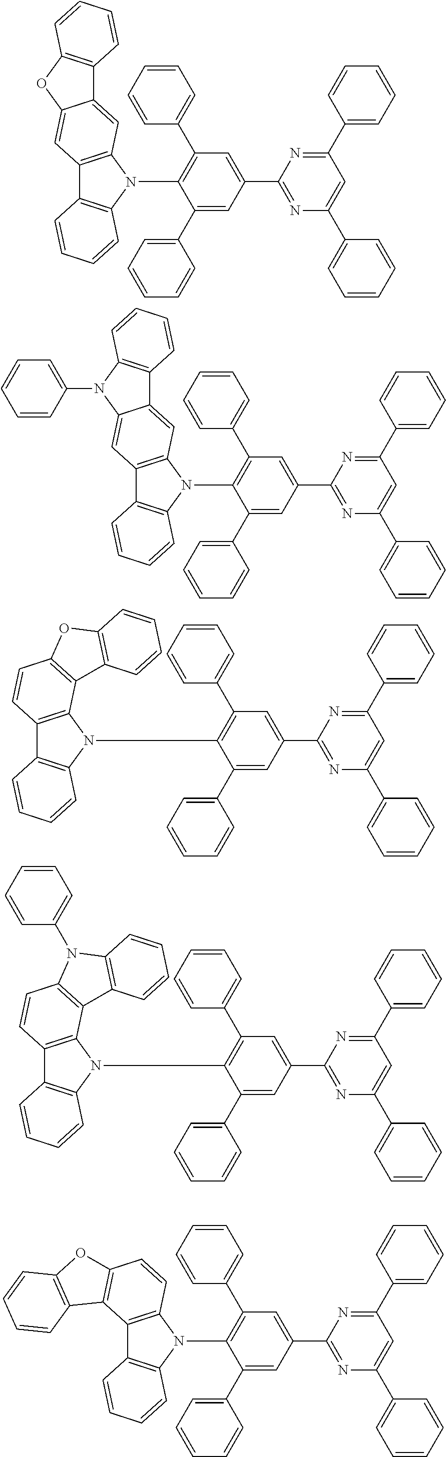

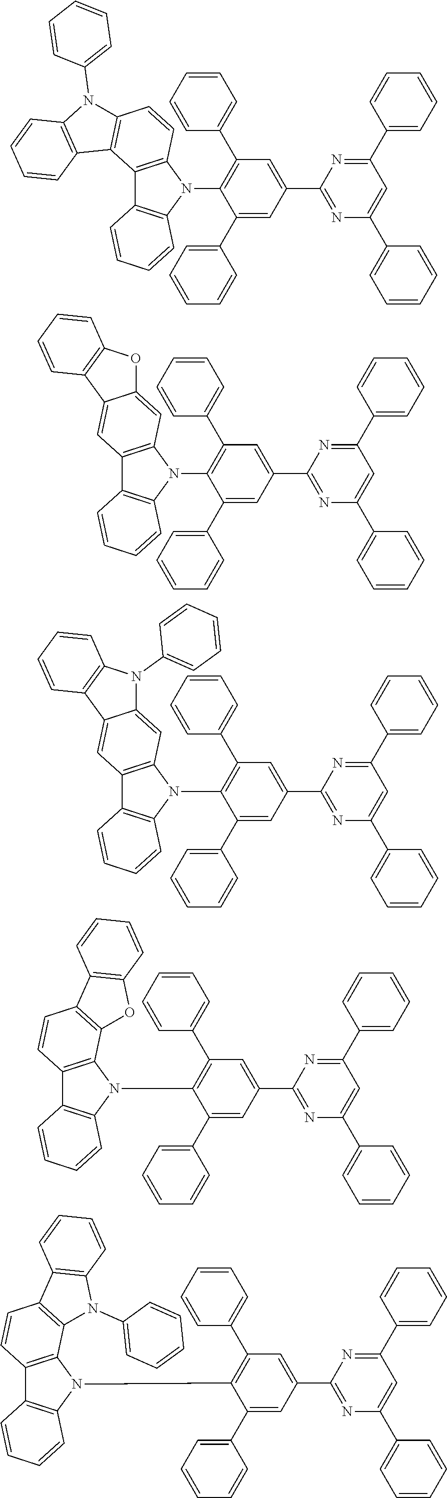

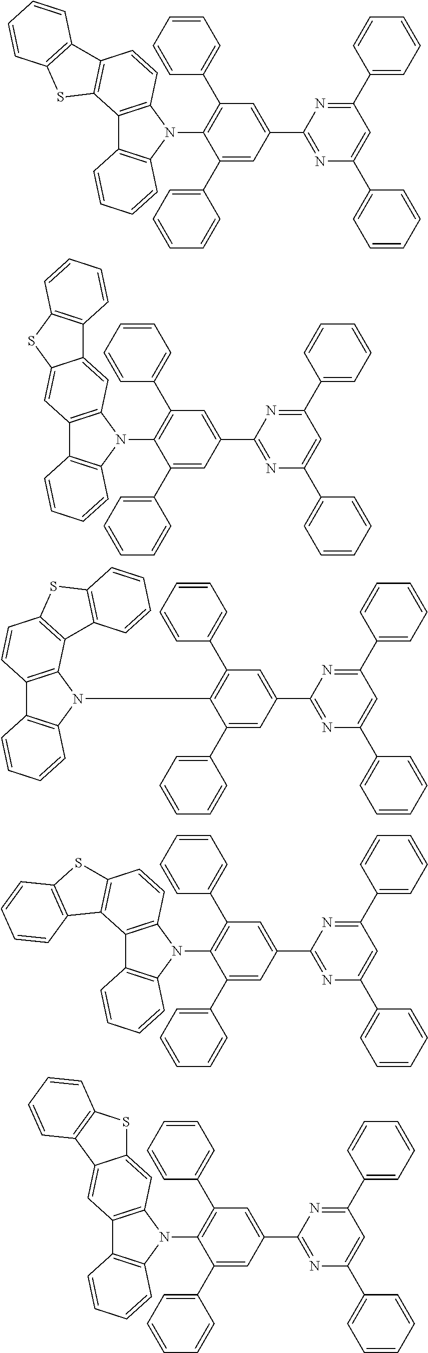

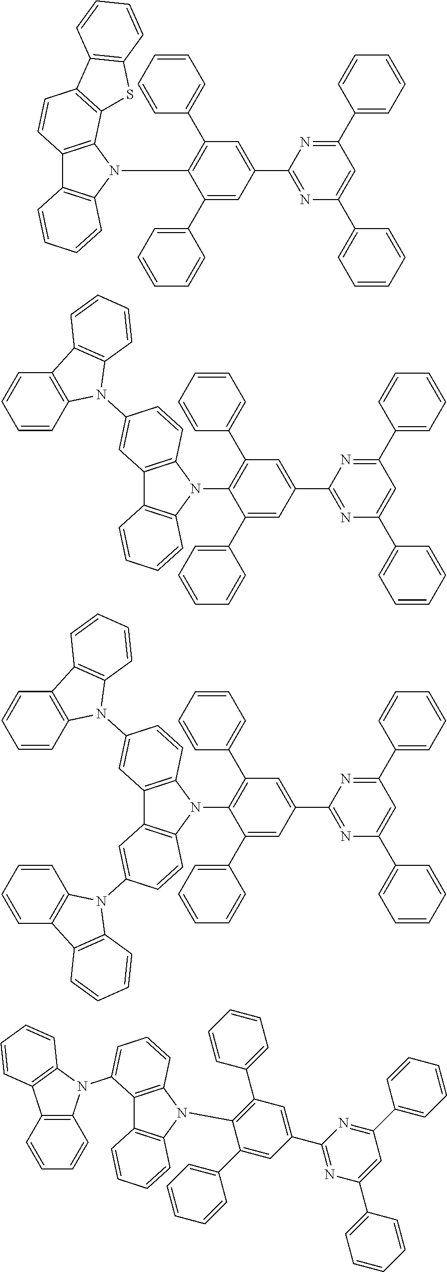

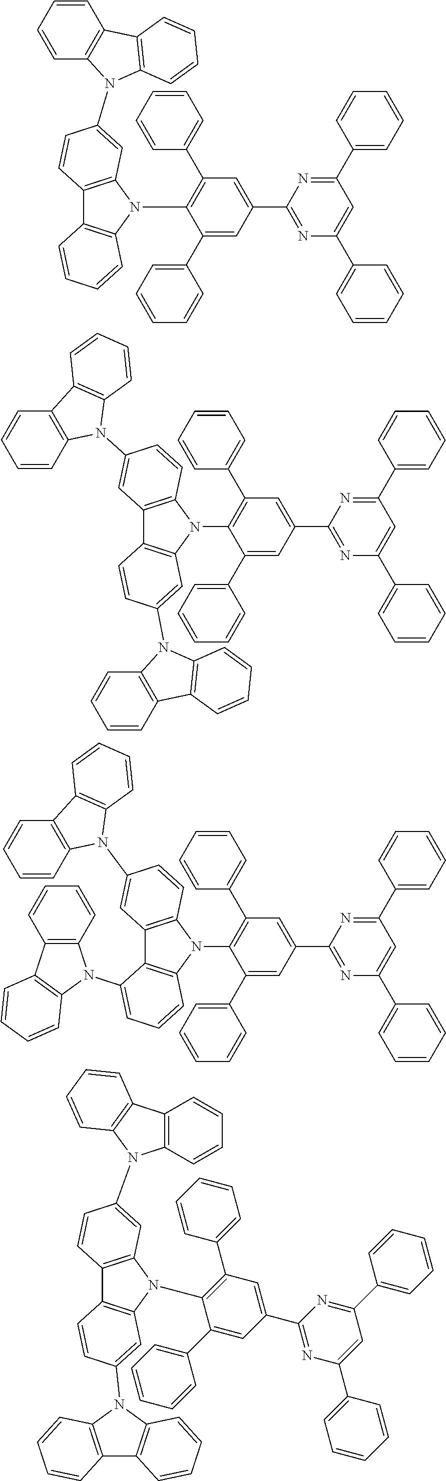

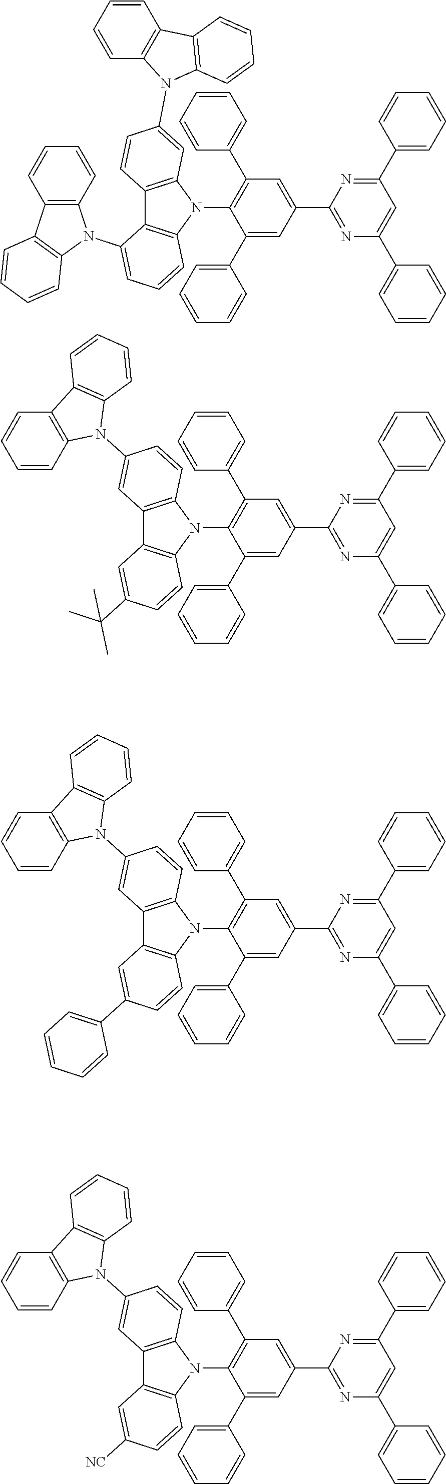 [SMILES: c1ccc(-c2cc(-c3ccccc3)nc(-c3cc(-c4ccccc4)c(-n4c5cc(-n6c7ccccc7c7ccccc76)ccc5c5c(-n6c7ccccc7c7ccccc76)cccc54)c(-c4ccccc4)c3)n2)cc1 ; CC(C)(C)c1ccc2c(c1)c1cc(-n3c4ccccc4c4ccccc43)ccc1n2-c1c(-c2ccccc2)cc(-c2nc(-c3ccccc3)cc(-c3ccccc3)n2)cc1-c1ccccc1 ; c1ccc(-c2ccc3c(c2)c2cc(-n4c5ccccc5c5ccccc54)ccc2n3-c2c(-c3ccccc3)cc(-c3nc(-c4ccccc4)cc(-c4ccccc4)n3)cc2-c2ccccc2)cc1 ; N#Cc1ccc2c(c1)c1cc(-n3c4ccccc4c4ccccc43)ccc1n2-c1c(-c2ccccc2)cc(-c2nc(-c3ccccc3)cc(-c3ccccc3)n2)cc1-c1ccccc1]

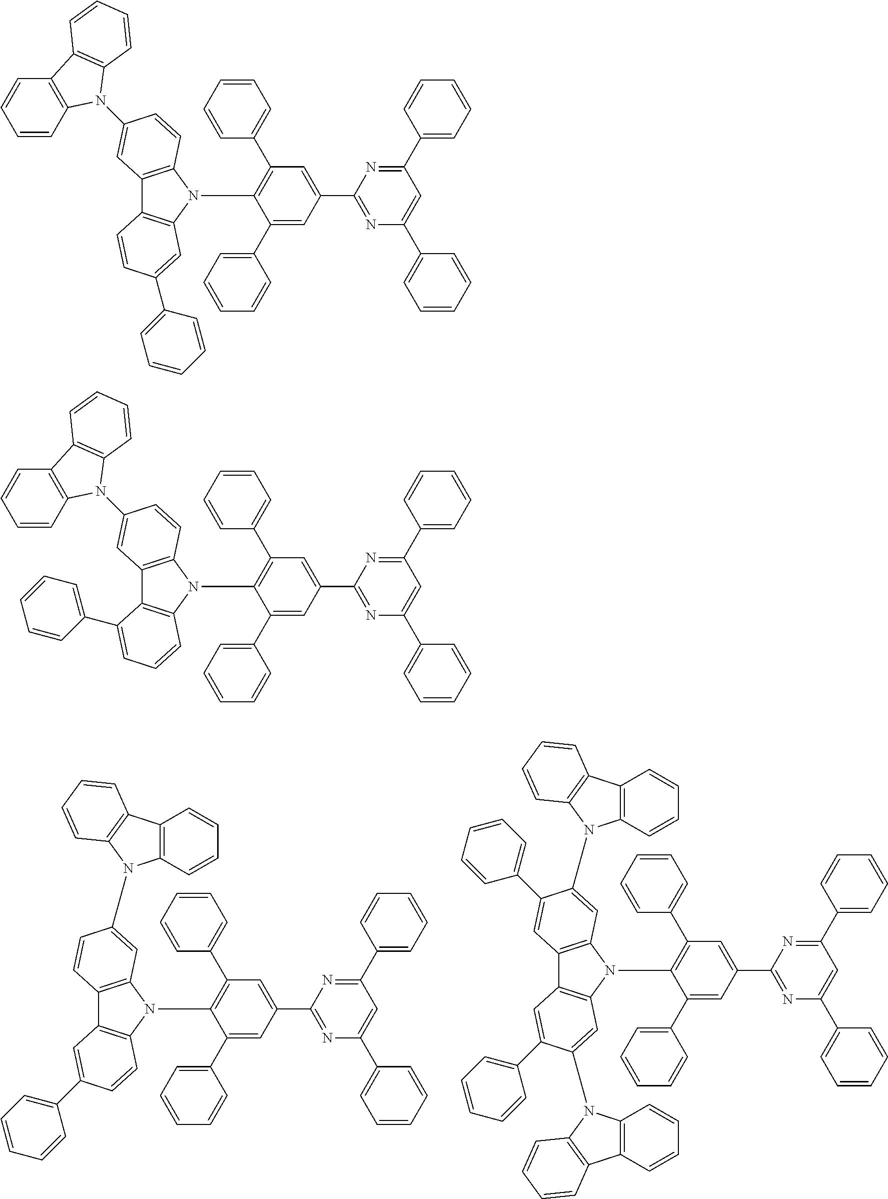

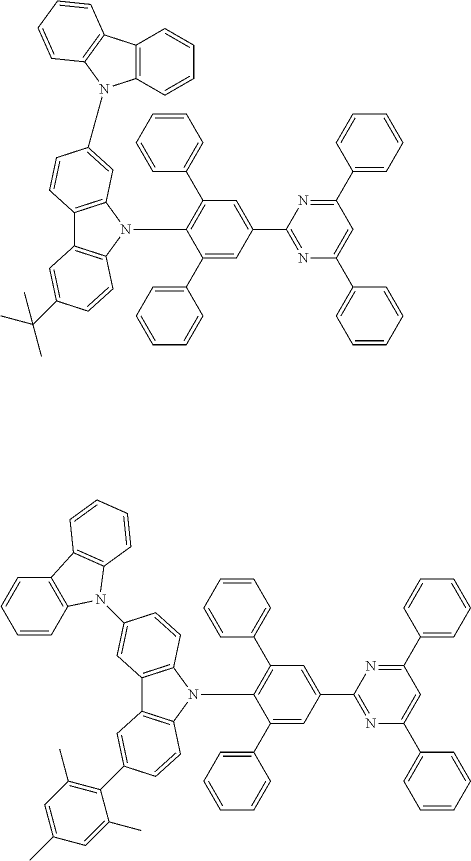 [SMILES: CC(C)(C)c1ccc2c(c1)c1ccc(-n3c4ccccc4c4ccccc43)cc1n2-c1c(-c2ccccc2)cc(-c2nc(-c3ccccc3)cc(-c3ccccc3)n2)cc1-c1ccccc1 ; Cc1cc(C)c(-c2ccc3c(c2)c2cc(-n4c5ccccc5c5ccccc54)ccc2n3-c2c(-c3ccccc3)cc(-c3nc(-c4ccccc4)cc(-c4ccccc4)n3)cc2-c2ccccc2)c(C)c1]

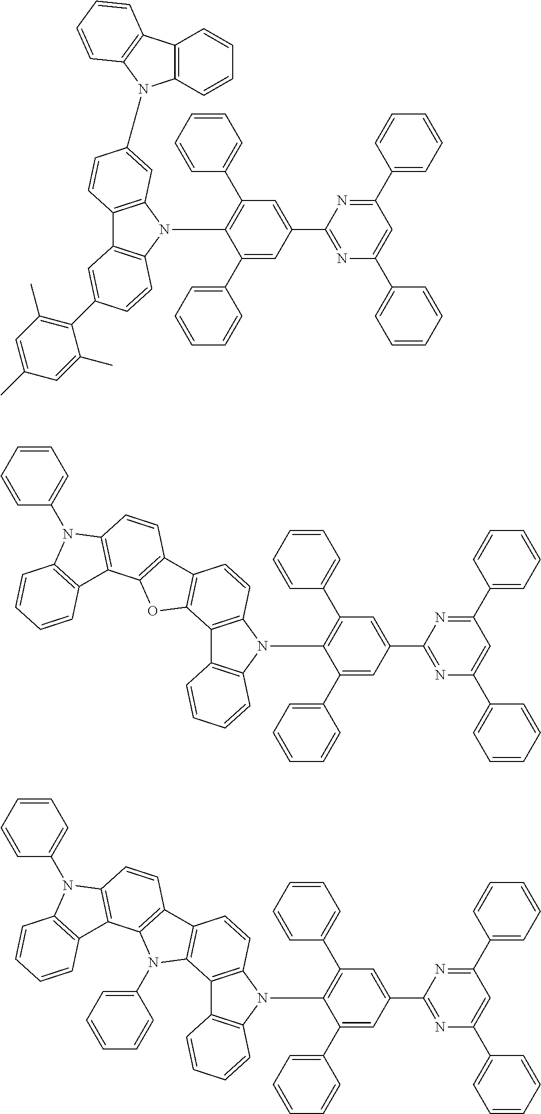 [SMILES: Cc1cc(C)c(-c2ccc3c(c2)c2ccc(-n4c5ccccc5c5ccccc54)cc2n3-c2c(-c3ccccc3)cc(-c3nc(-c4ccccc4)cc(-c4ccccc4)n3)cc2-c2ccccc2)c(C)c1 ; c1ccc(-c2cc(-c3ccccc3)nc(-c3cc(-c4ccccc4)c(-n4c5ccccc5c5c6oc7c(ccc8c7c7ccccc7n8-c7ccccc7)c6ccc54)c(-c4ccccc4)c3)n2)cc1 ; c1ccc(-c2cc(-c3ccccc3)nc(-c3cc(-c4ccccc4)c(-n4c5ccccc5c5c4ccc4c6ccc7c(c8ccccc8n7-c7ccccc7)c6n(-c6ccccc6)c45)c(-c4ccccc4)c3)n2)cc1]

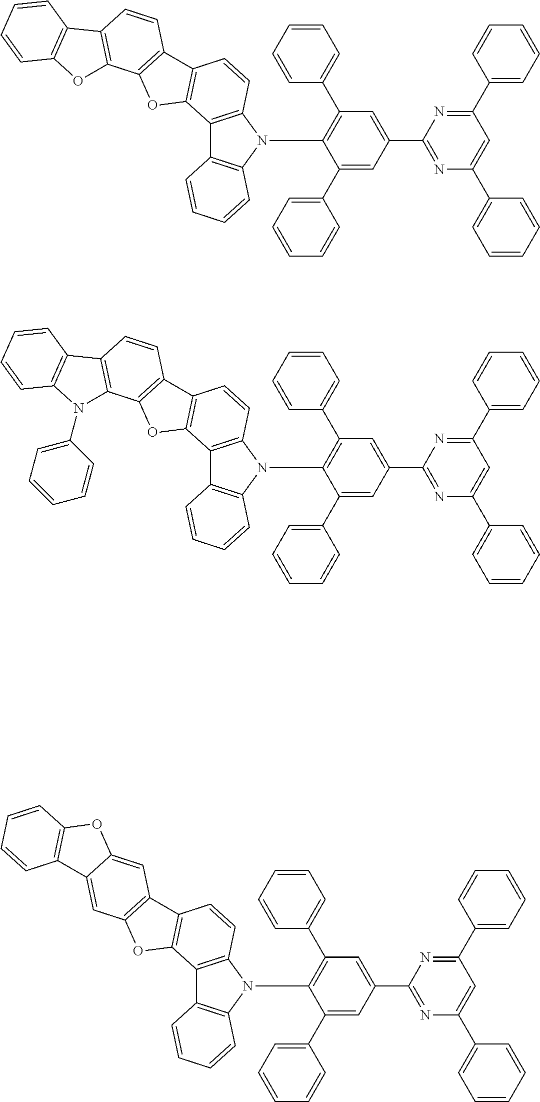 [SMILES: c1ccc(-c2cc(-c3ccccc3)nc(-c3cc(-c4ccccc4)c(-n4c5ccccc5c5c6oc7c(ccc8c9ccccc9oc87)c6ccc54)c(-c4ccccc4)c3)n2)cc1 ; c1ccc(-c2cc(-c3ccccc3)nc(-c3cc(-c4ccccc4)c(-n4c5ccccc5c5c6oc7c(ccc8c9ccccc9n(-c9ccccc9)c87)c6ccc54)c(-c4ccccc4)c3)n2)cc1 ; c1ccc(-c2cc(-c3ccccc3)nc(-c3cc(-c4ccccc4)c(-n4c5ccccc5c5c6oc7cc8c(cc7c6ccc54)oc4ccccc48)c(-c4ccccc4)c3)n2)cc1]

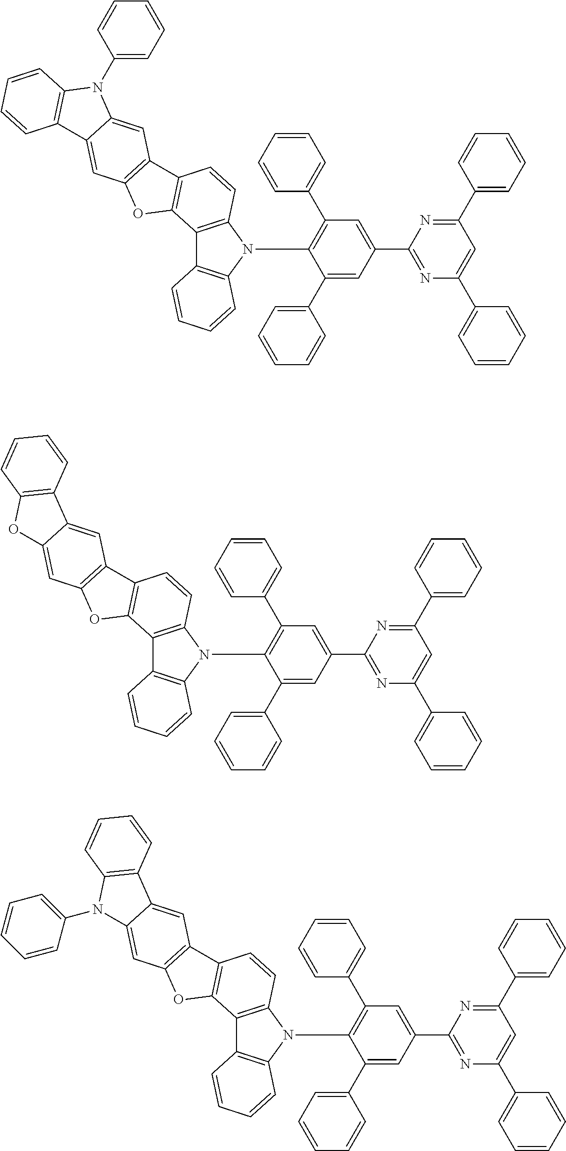 [SMILES: c1ccc(-c2cc(-c3ccccc3)nc(-c3cc(-c4ccccc4)c(-n4c5ccccc5c5c6oc7cc8c9ccccc9n(-c9ccccc9)c8cc7c6ccc54)c(-c4ccccc4)c3)n2)cc1 ; c1ccc(-c2cc(-c3ccccc3)nc(-c3cc(-c4ccccc4)c(-n4c5ccccc5c5c6oc7cc8oc9ccccc9c8cc7c6ccc54)c(-c4ccccc4)c3)n2)cc1 ; c1ccc(-c2cc(-c3ccccc3)nc(-c3cc(-c4ccccc4)c(-n4c5ccccc5c5c6oc7cc8c(cc7c6ccc54)c4ccccc4n8-c4ccccc4)c(-c4ccccc4)c3)n2)cc1]

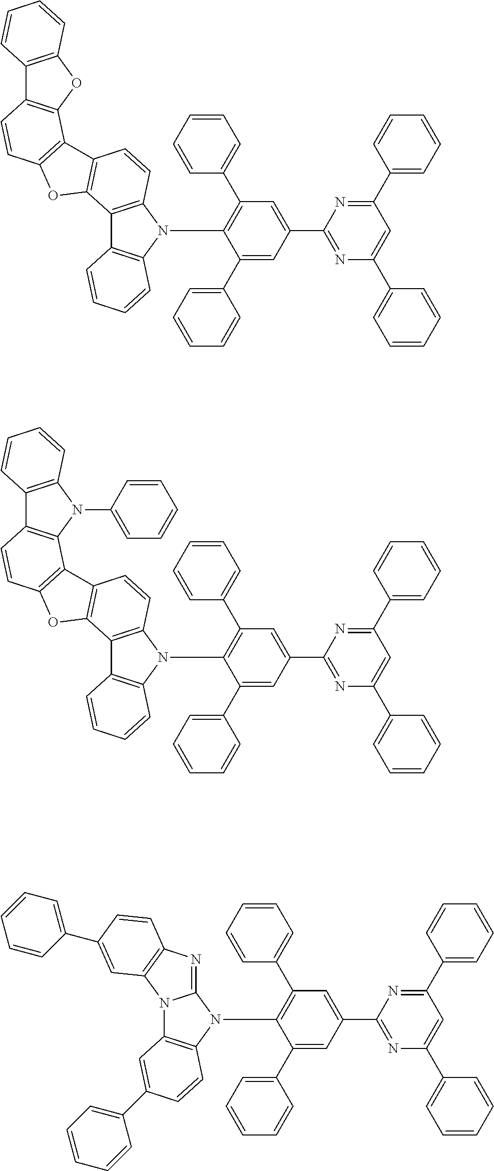 [SMILES: c1ccc(-c2cc(-c3ccccc3)nc(-c3cc(-c4ccccc4)c(-n4c5ccccc5c5c6oc7ccc8c9ccccc9oc8c7c6ccc54)c(-c4ccccc4)c3)n2)cc1 ; c1ccc(-c2cc(-c3ccccc3)nc(-c3cc(-c4ccccc4)c(-n4c5ccccc5c5c6oc7ccc8c9ccccc9n(-c9ccccc9)c8c7c6ccc54)c(-c4ccccc4)c3)n2)cc1 ; c1ccc(-c2ccc3nc4n(-c5c(-c6ccccc6)cc(-c6nc(-c7ccccc7)cc(-c7ccccc7)n6)cc5-c5ccccc5)c5ccc(-c6ccccc6)cc5n4c3c2)cc1]

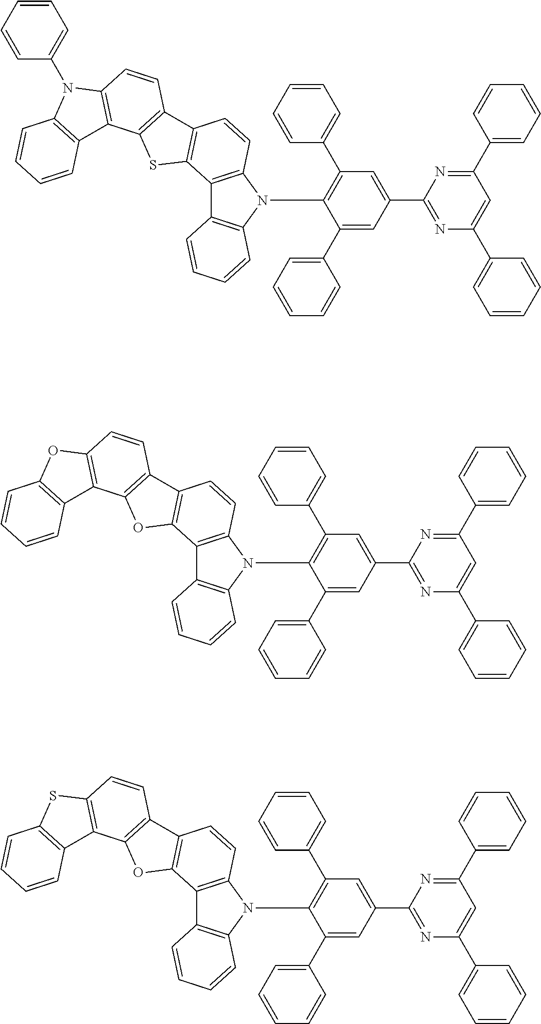 [SMILES: c1ccc(-c2cc(-c3ccccc3)nc(-c3cc(-c4ccccc4)c(-n4c5ccccc5c5c6sc7c(ccc8c7c7ccccc7n8-c7ccccc7)c6ccc54)c(-c4ccccc4)c3)n2)cc1 ; c1ccc(-c2cc(-c3ccccc3)nc(-c3cc(-c4ccccc4)c(-n4c5ccccc5c5c6oc7c(ccc8oc9ccccc9c87)c6ccc54)c(-c4ccccc4)c3)n2)cc1 ; c1ccc(-c2cc(-c3ccccc3)nc(-c3cc(-c4ccccc4)c(-n4c5ccccc5c5c6oc7c(ccc8sc9ccccc9c87)c6ccc54)c(-c4ccccc4)c3)n2)cc1]

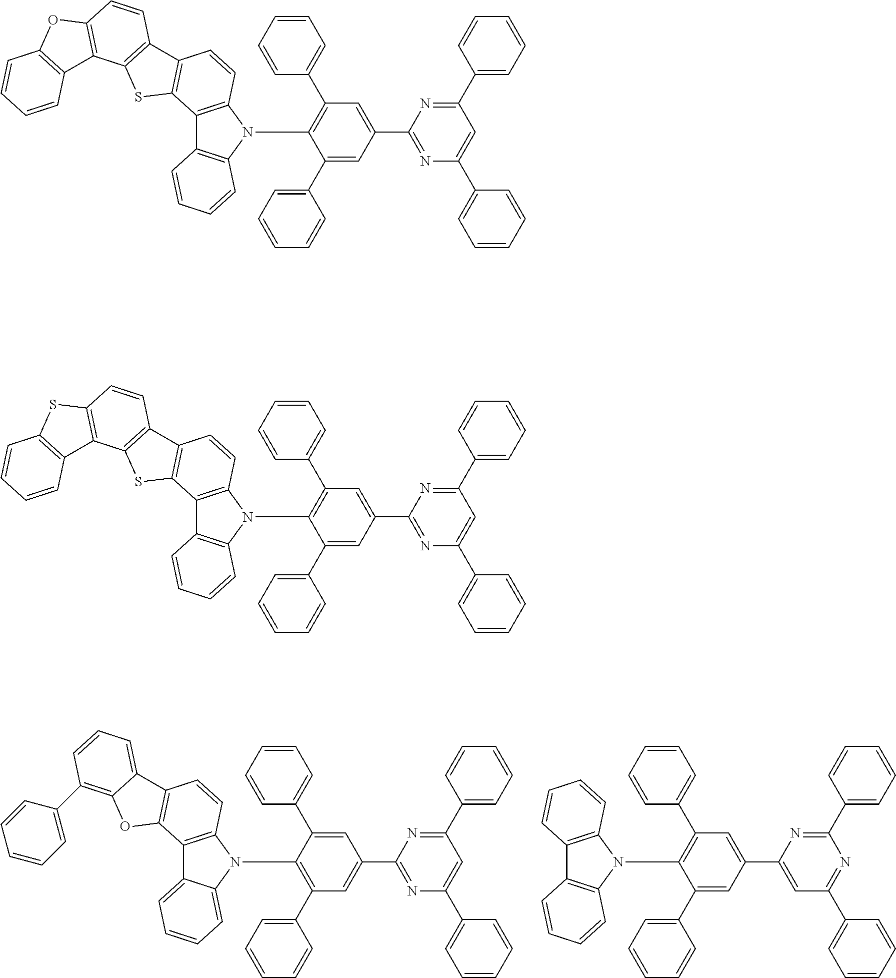

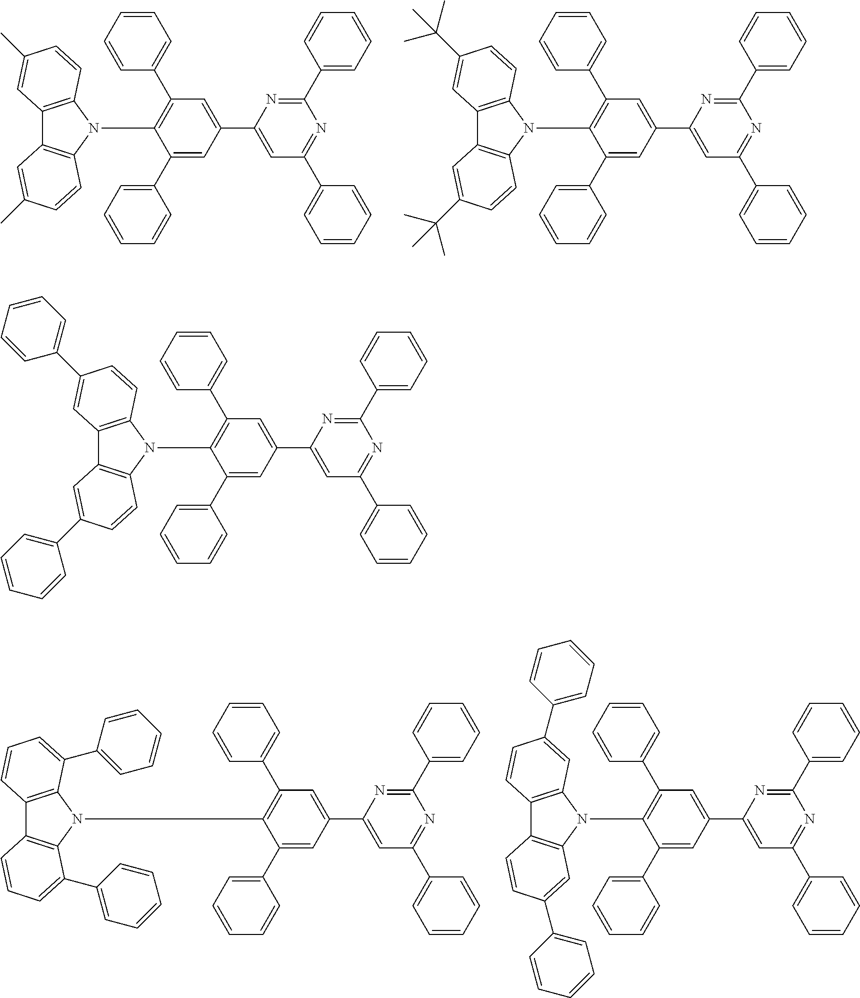

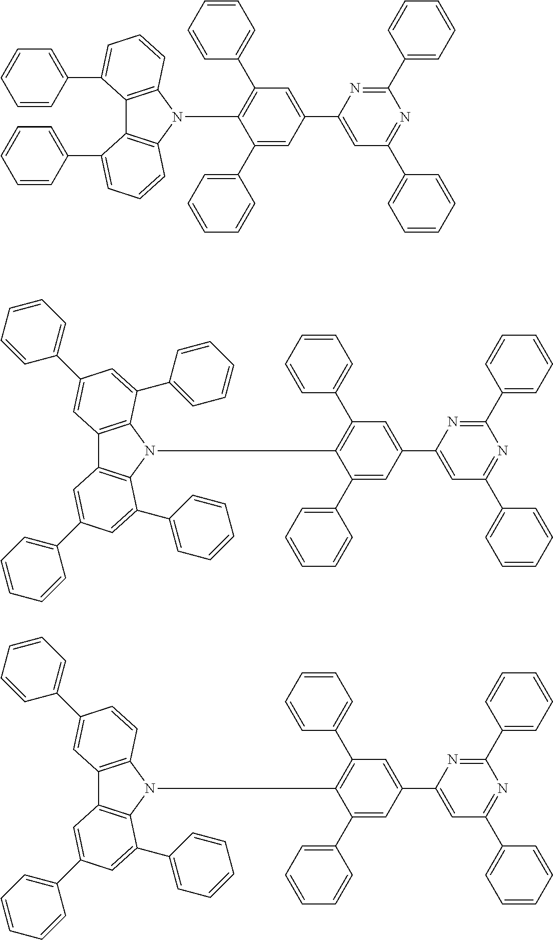

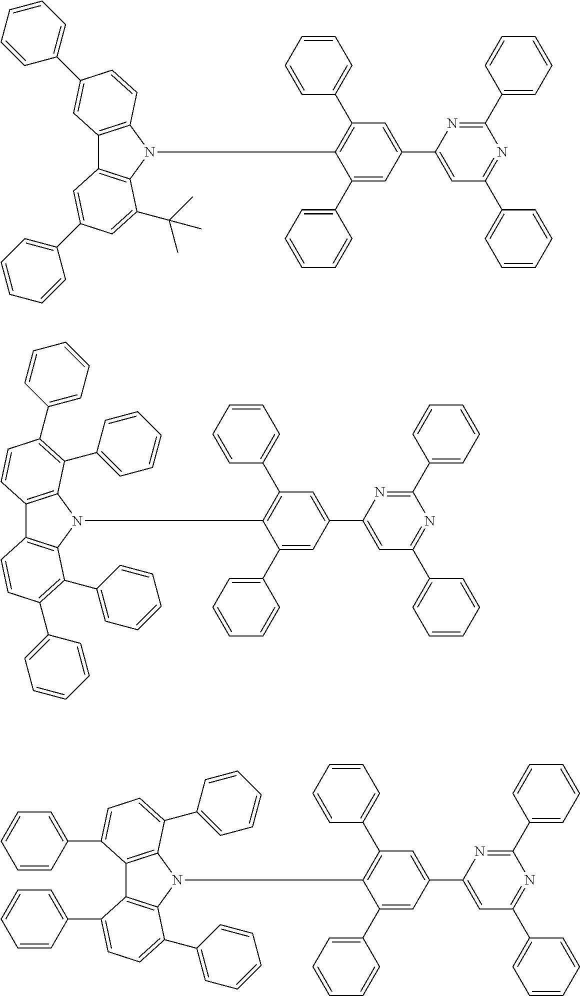

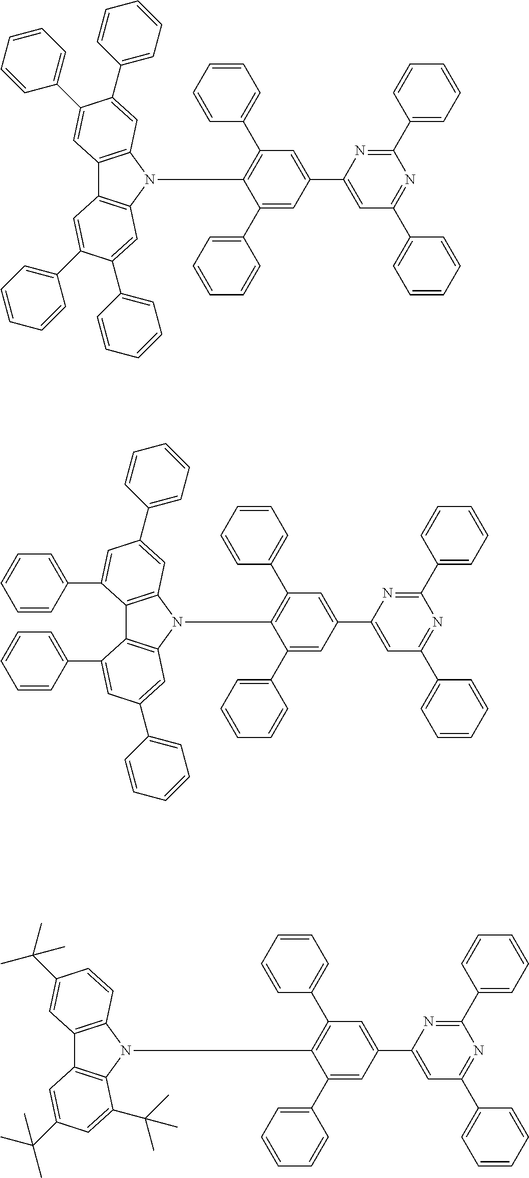 [SMILES: c1ccc(-c2cc(-c3cc(-c4ccccc4)c(-n4c5cc(-c6ccccc6)c(-c6ccccc6)cc5c5cc(-c6ccccc6)c(-c6ccccc6)cc54)c(-c4ccccc4)c3)nc(-c3ccccc3)n2)cc1 ; c1ccc(-c2cc(-c3ccccc3)c3c4c(-c5ccccc5)cc(-c5ccccc5)cc4n(-c4c(-c5ccccc5)cc(-c5cc(-c6ccccc6)nc(-c6ccccc6)n5)cc4-c4ccccc4)c3c2)cc1 ; CC(C)(C)c1ccc2c(c1)c1cc(C(C)(C)C)cc(C(C)(C)C)c1n2-c1c(-c2ccccc2)cc(-c2cc(-c3ccccc3)nc(-c3ccccc3)n2)cc1-c1ccccc1]

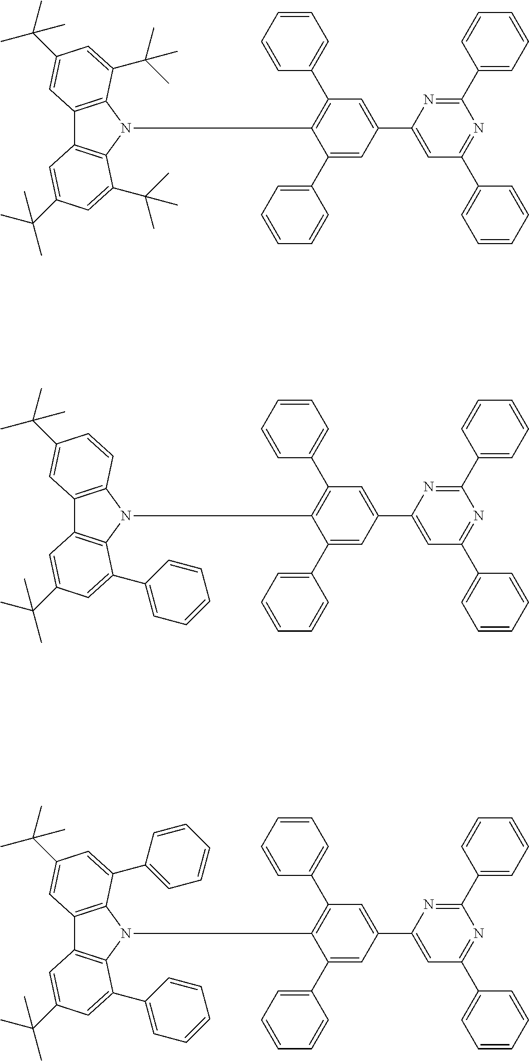 [SMILES: CC(C)(C)c1cc(C(C)(C)C)c2c(c1)c1cc(C(C)(C)C)cc(C(C)(C)C)c1n2-c1c(-c2ccccc2)cc(-c2cc(-c3ccccc3)nc(-c3ccccc3)n2)cc1-c1ccccc1 ; CC(C)(C)c1ccc2c(c1)c1cc(C(C)(C)C)cc(-c3ccccc3)c1n2-c1c(-c2ccccc2)cc(-c2cc(-c3ccccc3)nc(-c3ccccc3)n2)cc1-c1ccccc1 ; CC(C)(C)c1cc(-c2ccccc2)c2c(c1)c1cc(C(C)(C)C)cc(-c3ccccc3)c1n2-c1c(-c2ccccc2)cc(-c2cc(-c3ccccc3)nc(-c3ccccc3)n2)cc1-c1ccccc1]

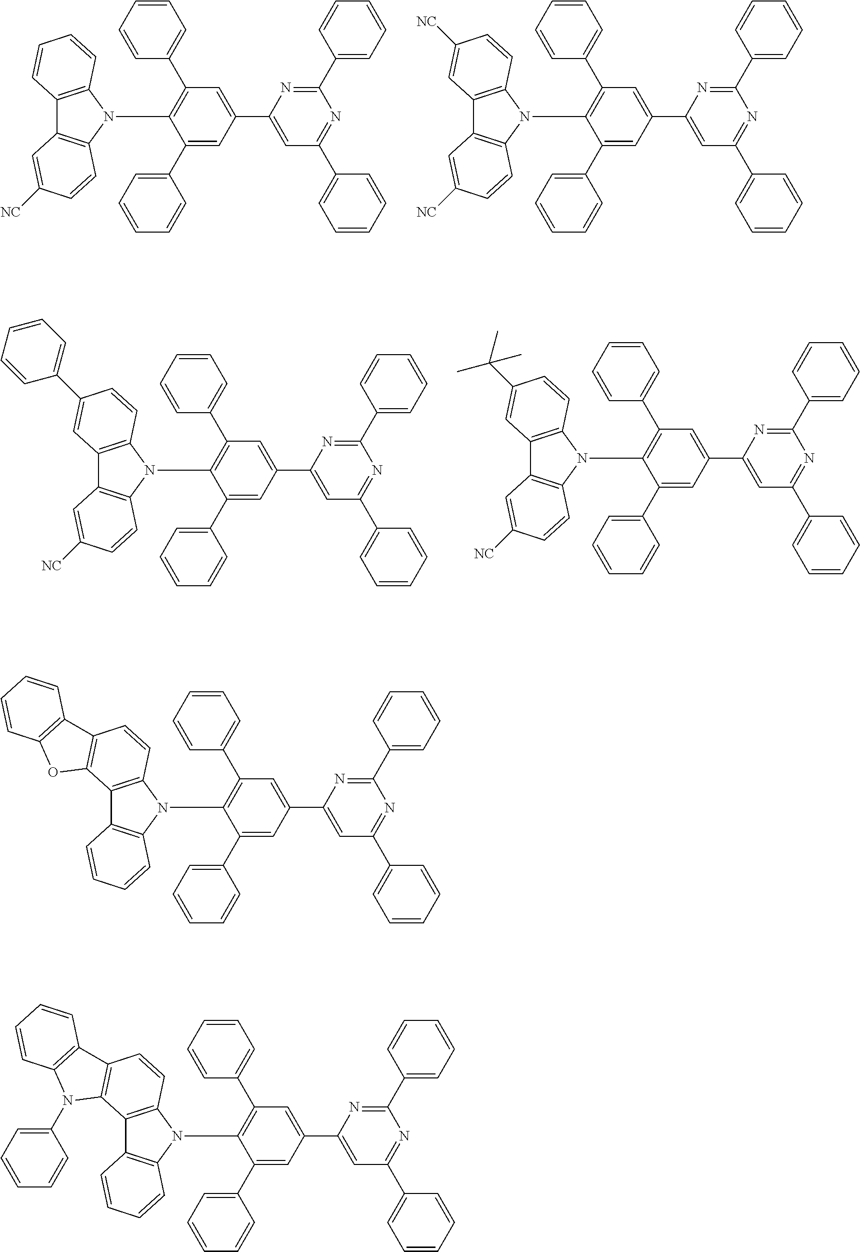

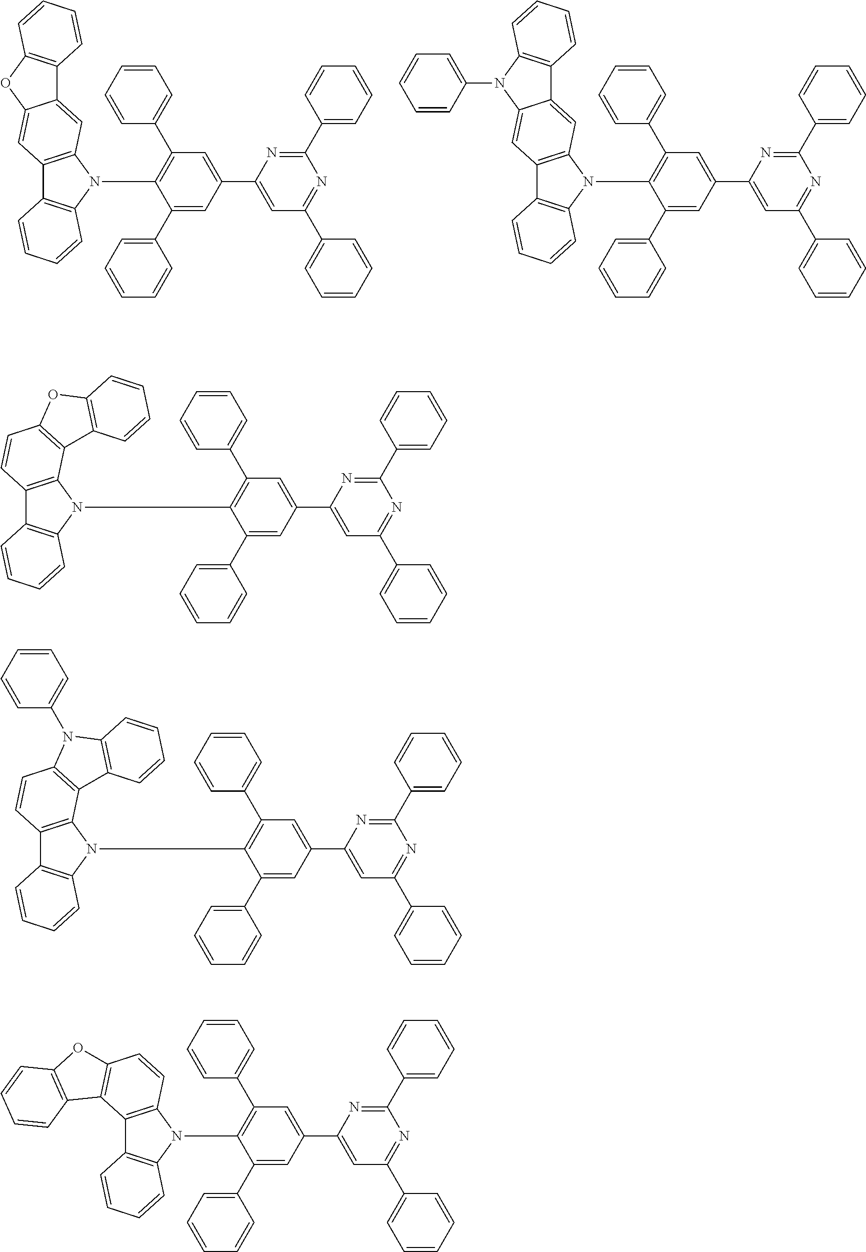

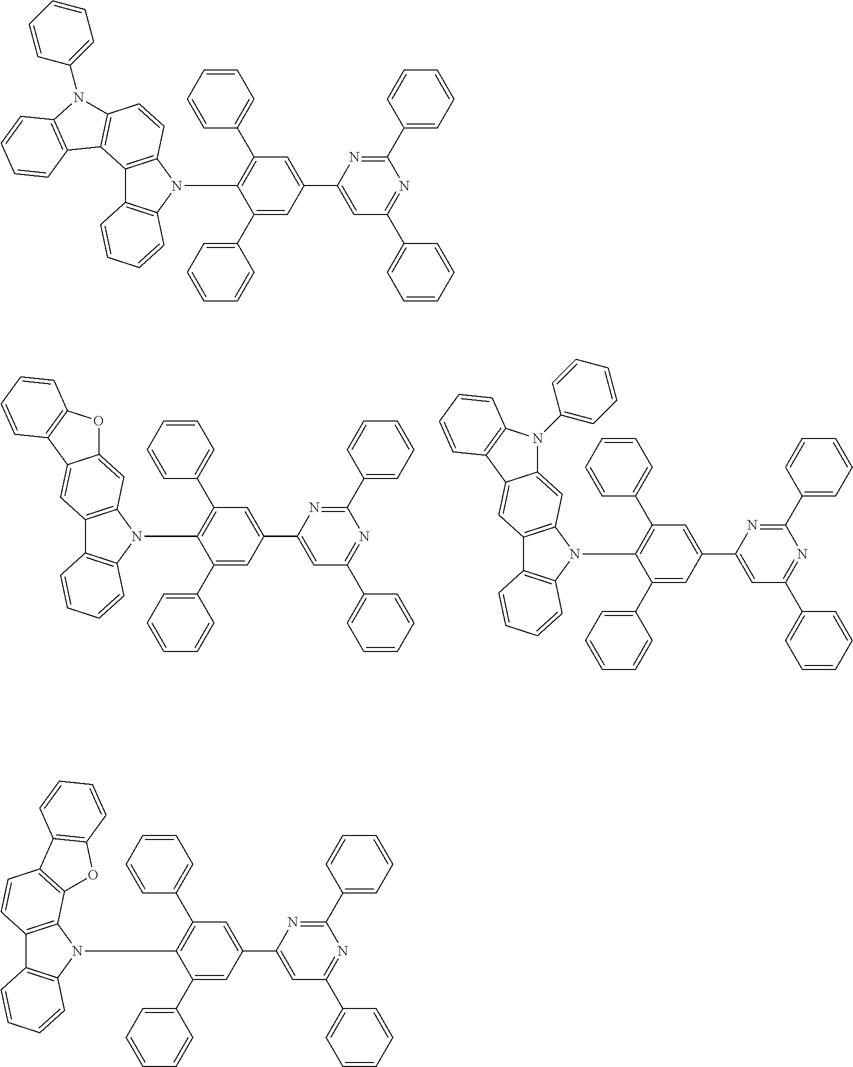

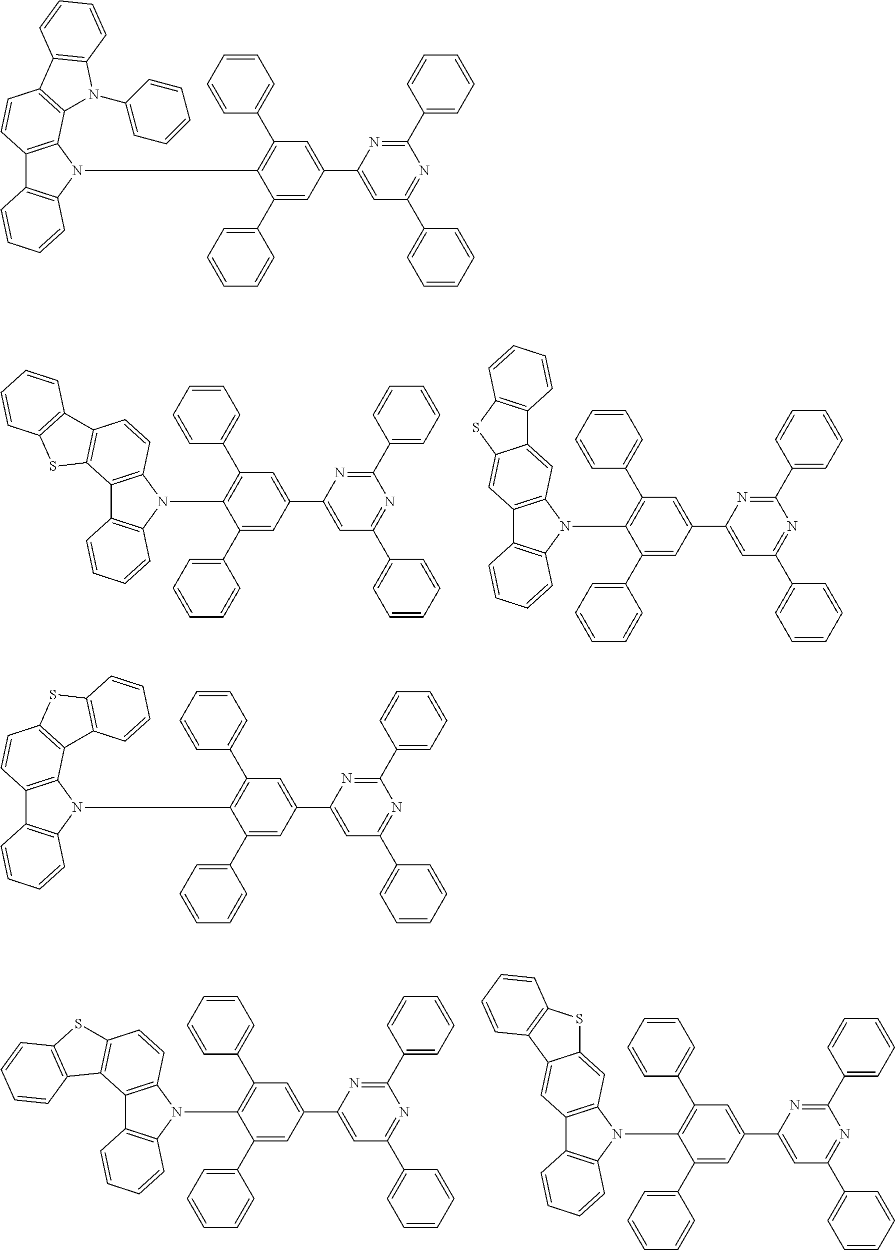

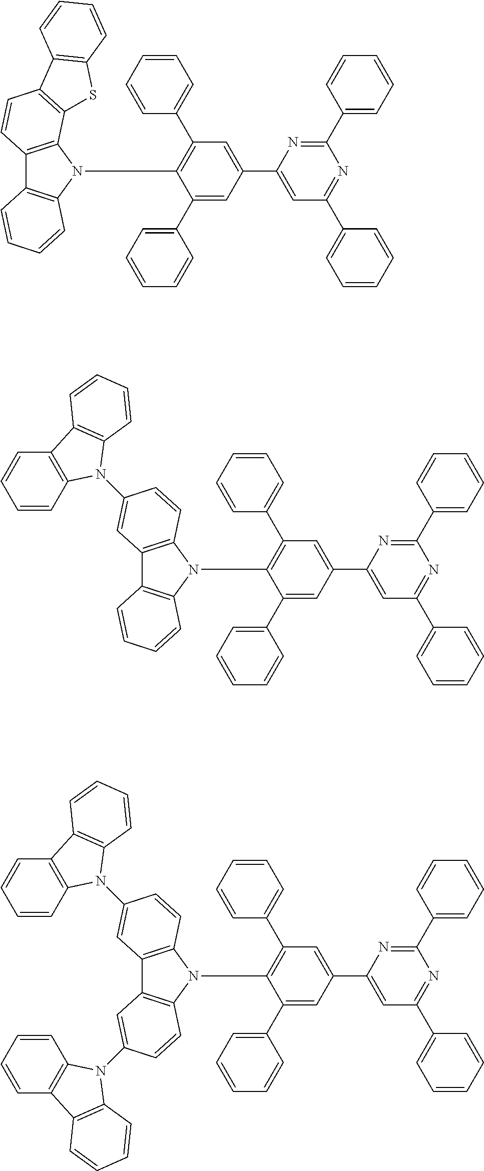 [SMILES: c1ccc(-c2cc(-c3cc(-c4ccccc4)c(-n4c5ccccc5c5ccc6c7ccccc7sc6c54)c(-c4ccccc4)c3)nc(-c3ccccc3)n2)cc1 ; c1ccc(-c2cc(-c3cc(-c4ccccc4)c(-n4c5ccccc5c5cc(-n6c7ccccc7c7ccccc76)ccc54)c(-c4ccccc4)c3)nc(-c3ccccc3)n2)cc1 ; c1ccc(-c2cc(-c3cc(-c4ccccc4)c(-n4c5ccc(-n6c7ccccc7c7ccccc76)cc5c5cc(-n6c7ccccc7c7ccccc76)ccc54)c(-c4ccccc4)c3)nc(-c3ccccc3)n2)cc1]

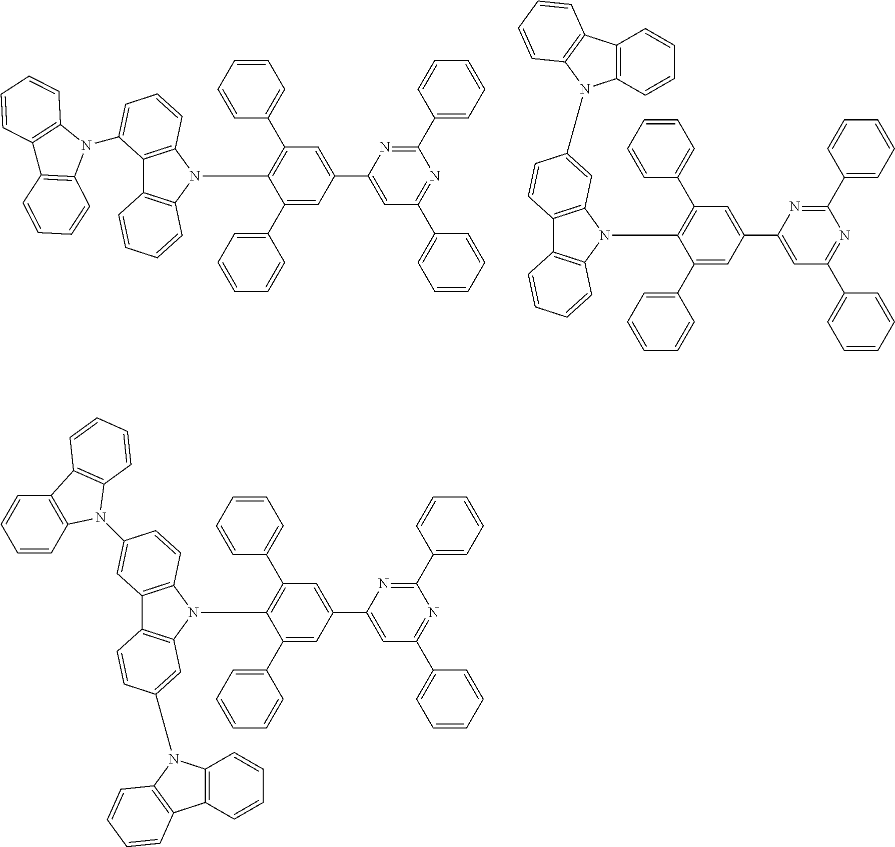

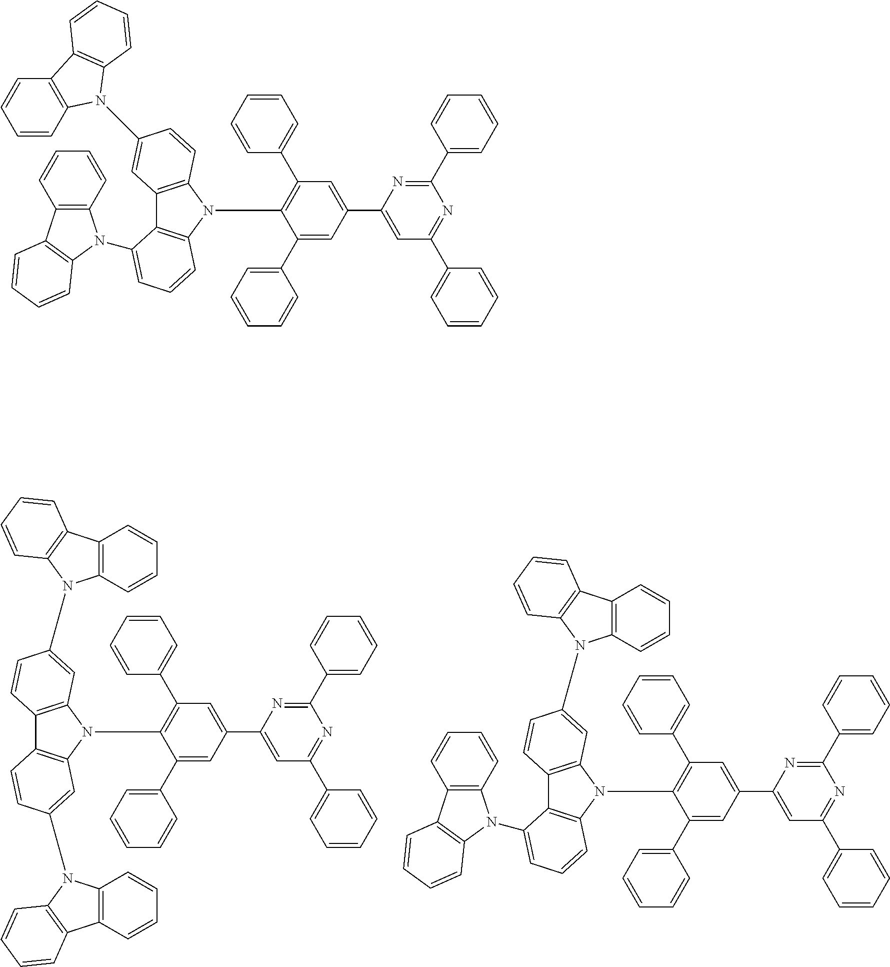

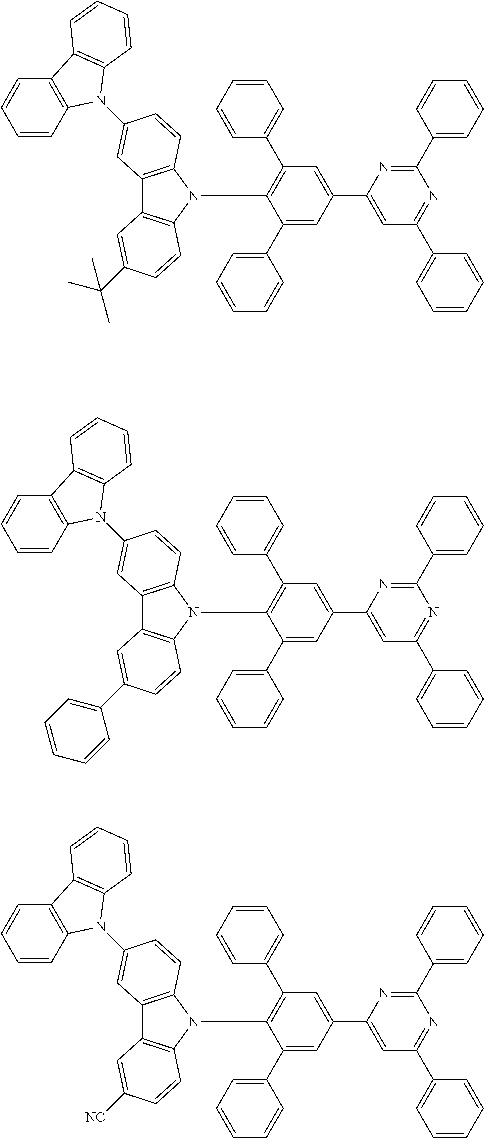 [SMILES: CC(C)(C)c1ccc2c(c1)c1cc(-n3c4ccccc4c4ccccc43)ccc1n2-c1c(-c2ccccc2)cc(-c2cc(-c3ccccc3)nc(-c3ccccc3)n2)cc1-c1ccccc1 ; c1ccc(-c2ccc3c(c2)c2cc(-n4c5ccccc5c5ccccc54)ccc2n3-c2c(-c3ccccc3)cc(-c3cc(-c4ccccc4)nc(-c4ccccc4)n3)cc2-c2ccccc2)cc1 ; N#Cc1ccc2c(c1)c1cc(-n3c4ccccc4c4ccccc43)ccc1n2-c1c(-c2ccccc2)cc(-c2cc(-c3ccccc3)nc(-c3ccccc3)n2)cc1-c1ccccc1]

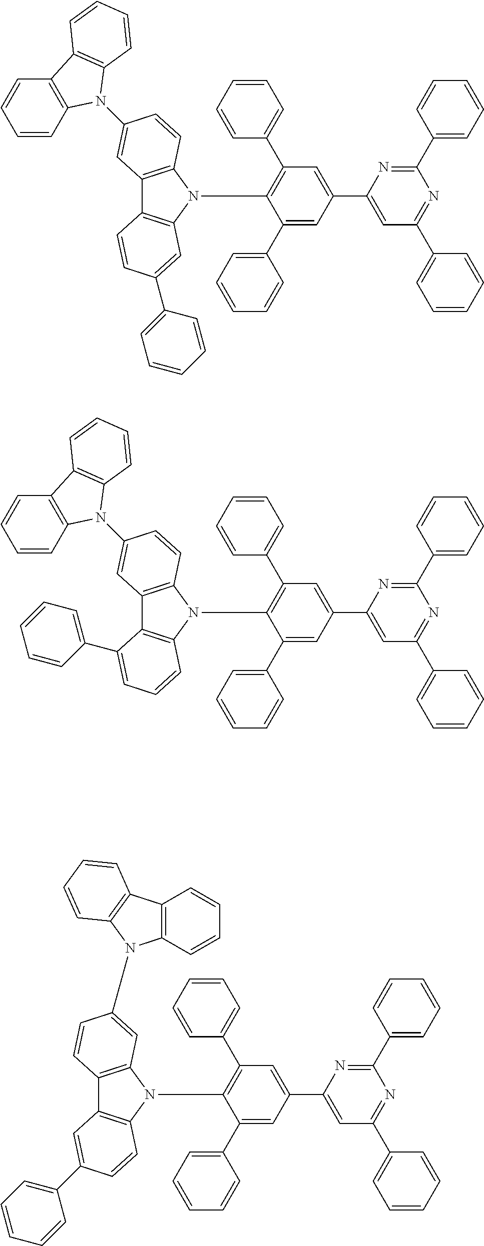 [SMILES: c1ccc(-c2ccc3c4cc(-n5c6ccccc6c6ccccc65)ccc4n(-c4c(-c5ccccc5)cc(-c5cc(-c6ccccc6)nc(-c6ccccc6)n5)cc4-c4ccccc4)c3c2)cc1 ; c1ccc(-c2cc(-c3cc(-c4ccccc4)c(-n4c5ccc(-n6c7ccccc7c7ccccc76)cc5c5c(-c6ccccc6)cccc54)c(-c4ccccc4)c3)nc(-c3ccccc3)n2)cc1 ; c1ccc(-c2ccc3c(c2)c2ccc(-n4c5ccccc5c5ccccc54)cc2n3-c2c(-c3ccccc3)cc(-c3cc(-c4ccccc4)nc(-c4ccccc4)n3)cc2-c2ccccc2)cc1]

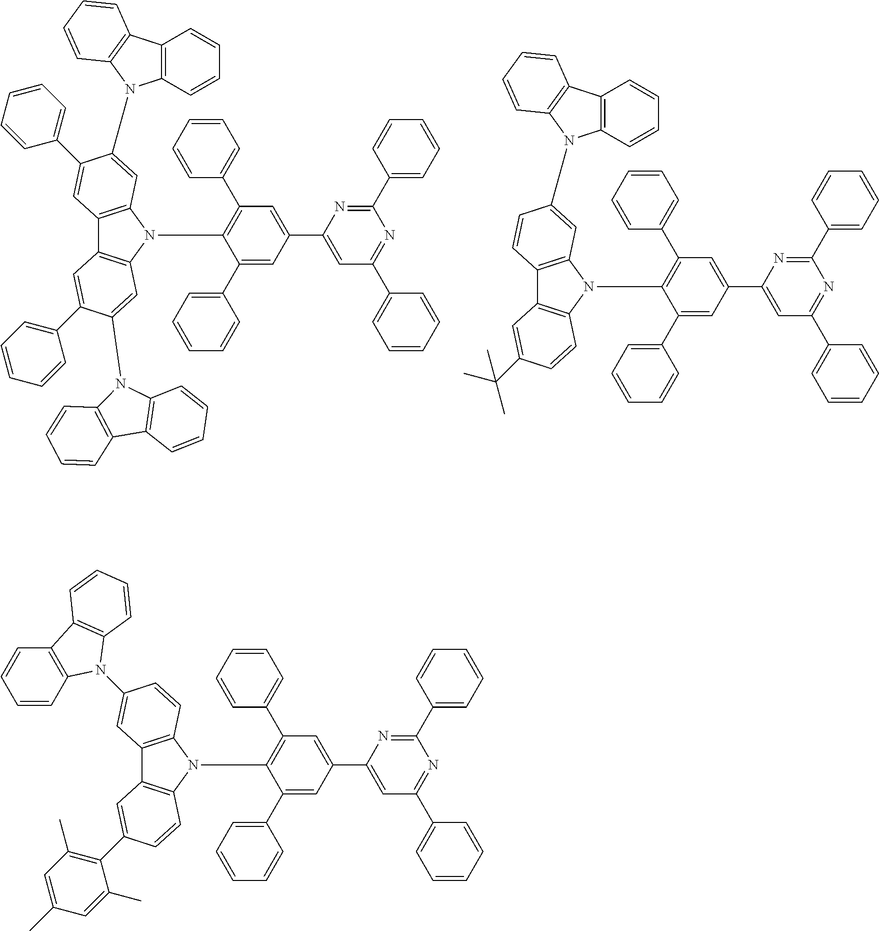 [SMILES: c1ccc(-c2cc(-c3cc(-c4ccccc4)c(-n4c5cc(-n6c7ccccc7c7ccccc76)c(-c6ccccc6)cc5c5cc(-c6ccccc6)c(-n6c7ccccc7c7ccccc76)cc54)c(-c4ccccc4)c3)nc(-c3ccccc3)n2)cc1 ; CC(C)(C)c1ccc2c(c1)c1ccc(-n3c4ccccc4c4ccccc43)cc1n2-c1c(-c2ccccc2)cc(-c2cc(-c3ccccc3)nc(-c3ccccc3)n2)cc1-c1ccccc1 ; Cc1cc(C)c(-c2ccc3c(c2)c2cc(-n4c5ccccc5c5ccccc54)ccc2n3-c2c(-c3ccccc3)cc(-c3cc(-c4ccccc4)nc(-c4ccccc4)n3)cc2-c2ccccc2)c(C)c1]

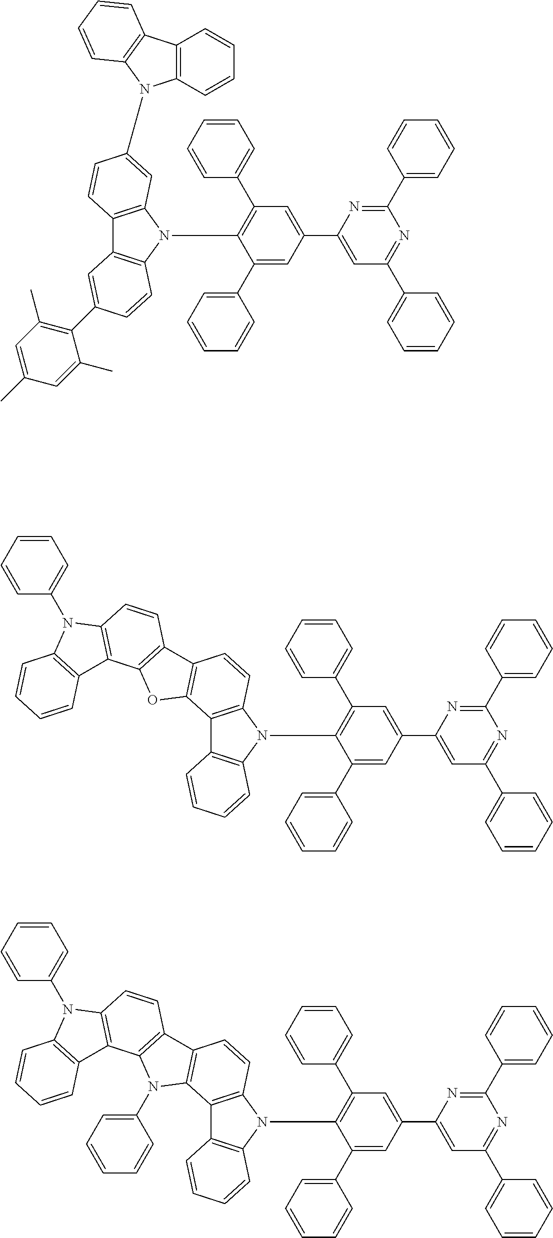 [SMILES: Cc1cc(C)c(-c2ccc3c(c2)c2ccc(-n4c5ccccc5c5ccccc54)cc2n3-c2c(-c3ccccc3)cc(-c3cc(-c4ccccc4)nc(-c4ccccc4)n3)cc2-c2ccccc2)c(C)c1 ; c1ccc(-c2cc(-c3cc(-c4ccccc4)c(-n4c5ccccc5c5c6oc7c(ccc8c7c7ccccc7n8-c7ccccc7)c6ccc54)c(-c4ccccc4)c3)nc(-c3ccccc3)n2)cc1 ; c1ccc(-c2cc(-c3cc(-c4ccccc4)c(-n4c5ccccc5c5c4ccc4c6ccc7c(c8ccccc8n7-c7ccccc7)c6n(-c6ccccc6)c45)c(-c4ccccc4)c3)nc(-c3ccccc3)n2)cc1]

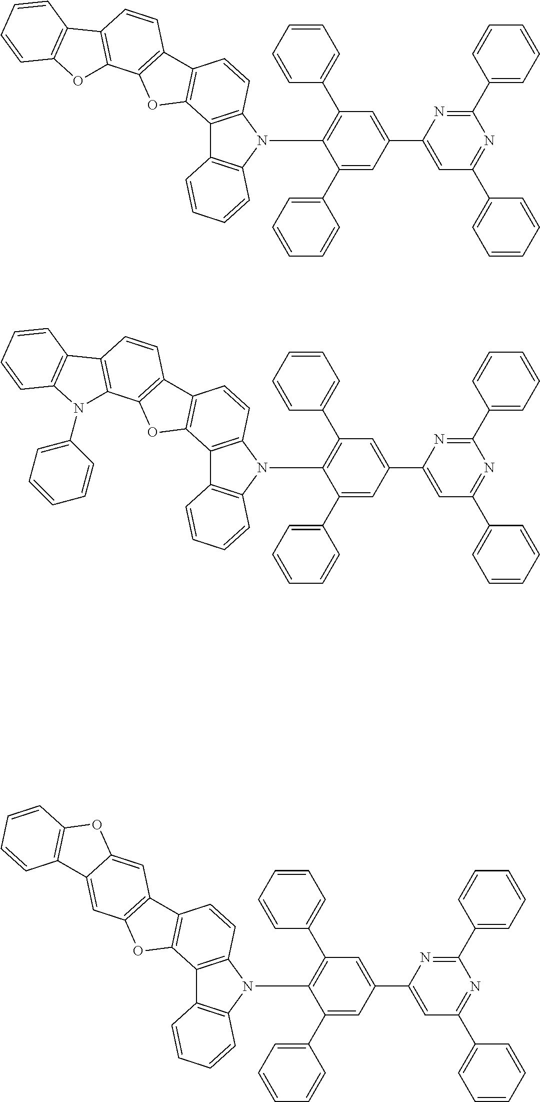 [SMILES: c1ccc(-c2cc(-c3cc(-c4ccccc4)c(-n4c5ccccc5c5c6oc7c(ccc8c9ccccc9oc87)c6ccc54)c(-c4ccccc4)c3)nc(-c3ccccc3)n2)cc1 ; c1ccc(-c2cc(-c3cc(-c4ccccc4)c(-n4c5ccccc5c5c6oc7c(ccc8c9ccccc9n(-c9ccccc9)c87)c6ccc54)c(-c4ccccc4)c3)nc(-c3ccccc3)n2)cc1 ; c1ccc(-c2cc(-c3cc(-c4ccccc4)c(-n4c5ccccc5c5c6oc7cc8c(cc7c6ccc54)oc4ccccc48)c(-c4ccccc4)c3)nc(-c3ccccc3)n2)cc1]

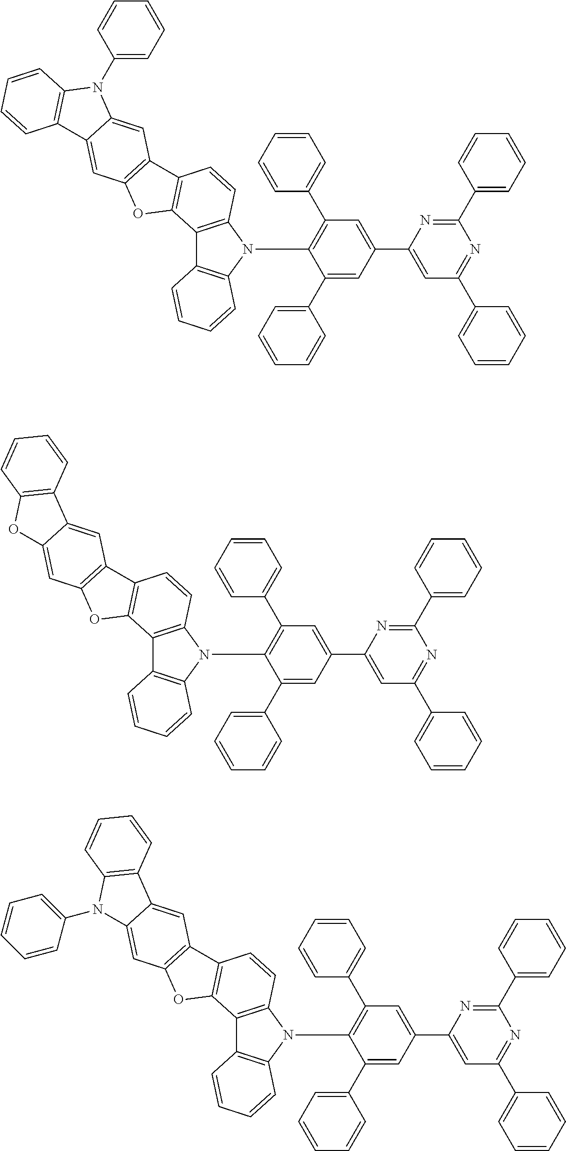 [SMILES: c1ccc(-c2cc(-c3cc(-c4ccccc4)c(-n4c5ccccc5c5c6oc7cc8c9ccccc9n(-c9ccccc9)c8cc7c6ccc54)c(-c4ccccc4)c3)nc(-c3ccccc3)n2)cc1 ; c1ccc(-c2cc(-c3cc(-c4ccccc4)c(-n4c5ccccc5c5c6oc7cc8oc9ccccc9c8cc7c6ccc54)c(-c4ccccc4)c3)nc(-c3ccccc3)n2)cc1 ; c1ccc(-c2cc(-c3cc(-c4ccccc4)c(-n4c5ccccc5c5c6oc7cc8c(cc7c6ccc54)c4ccccc4n8-c4ccccc4)c(-c4ccccc4)c3)nc(-c3ccccc3)n2)cc1]

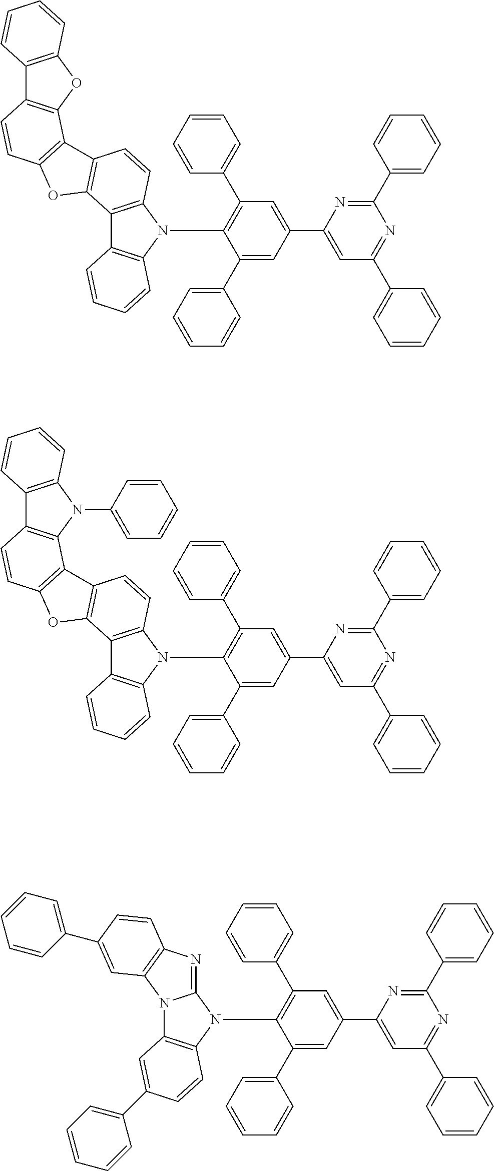 [SMILES: c1ccc(-c2cc(-c3cc(-c4ccccc4)c(-n4c5ccccc5c5c6oc7ccc8c9ccccc9oc8c7c6ccc54)c(-c4ccccc4)c3)nc(-c3ccccc3)n2)cc1 ; c1ccc(-c2cc(-c3cc(-c4ccccc4)c(-n4c5ccccc5c5c6oc7ccc8c9ccccc9n(-c9ccccc9)c8c7c6ccc54)c(-c4ccccc4)c3)nc(-c3ccccc3)n2)cc1 ; c1ccc(-c2ccc3nc4n(-c5c(-c6ccccc6)cc(-c6cc(-c7ccccc7)nc(-c7ccccc7)n6)cc5-c5ccccc5)c5ccc(-c6ccccc6)cc5n4c3c2)cc1]

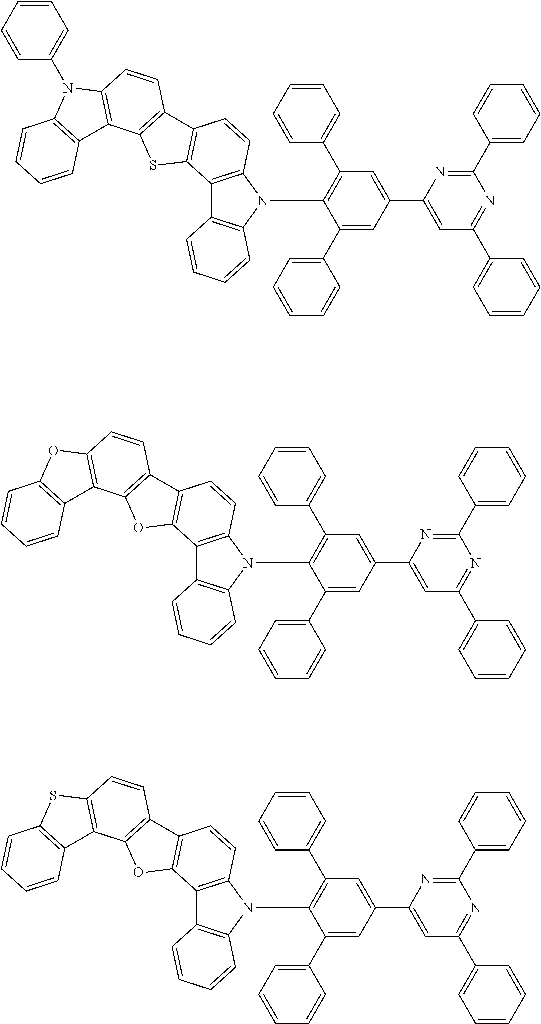 [SMILES: c1ccc(-c2cc(-c3cc(-c4ccccc4)c(-n4c5ccccc5c5c6sc7c(ccc8c7c7ccccc7n8-c7ccccc7)c6ccc54)c(-c4ccccc4)c3)nc(-c3ccccc3)n2)cc1 ; c1ccc(-c2cc(-c3cc(-c4ccccc4)c(-n4c5ccccc5c5c6oc7c(ccc8oc9ccccc9c87)c6ccc54)c(-c4ccccc4)c3)nc(-c3ccccc3)n2)cc1 ; c1ccc(-c2cc(-c3cc(-c4ccccc4)c(-n4c5ccccc5c5c6oc7c(ccc8sc9ccccc9c87)c6ccc54)c(-c4ccccc4)c3)nc(-c3ccccc3)n2)cc1]

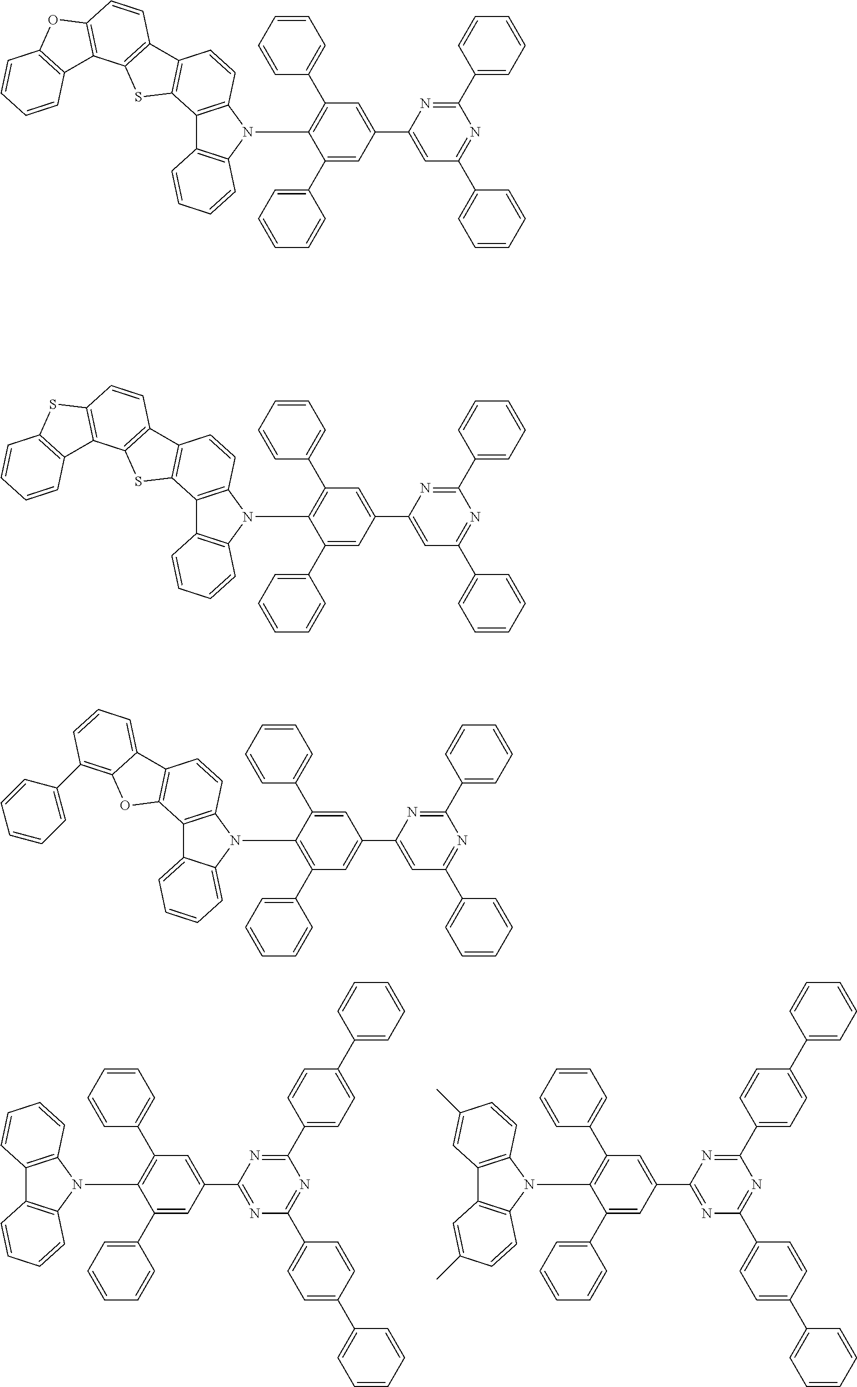

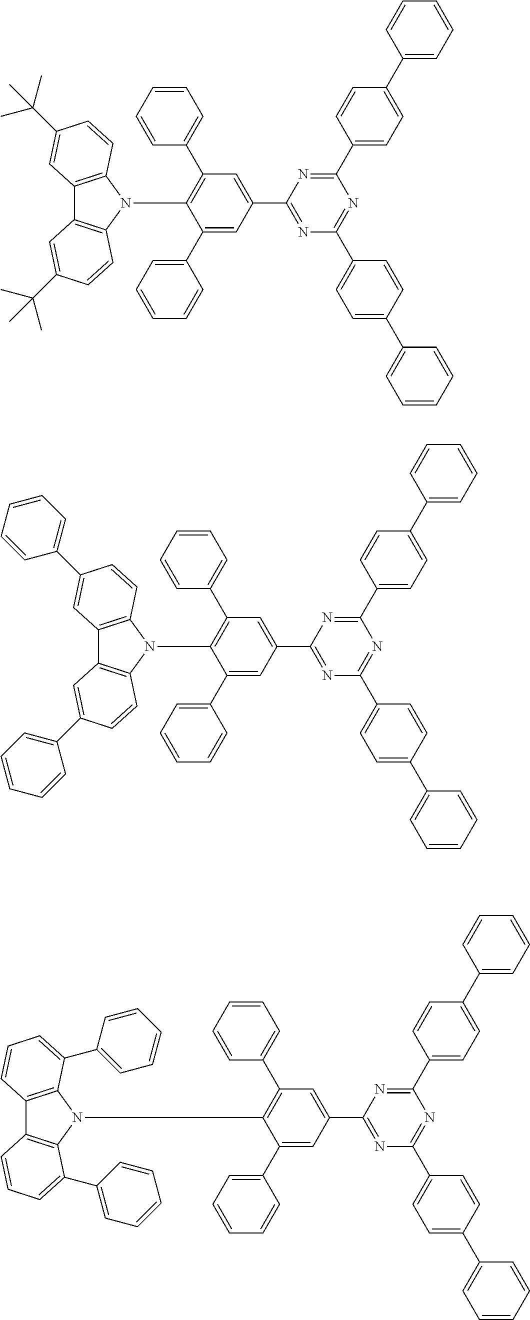

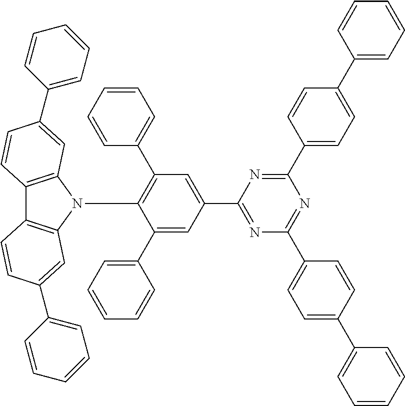 [SMILES: c1ccc(-c2ccc(-c3nc(-c4ccc(-c5ccccc5)cc4)nc(-c4cc(-c5ccccc5)c(-n5c6cc(-c7ccccc7)ccc6c6ccc(-c7ccccc7)cc65)c(-c5ccccc5)c4)n3)cc2)cc1]

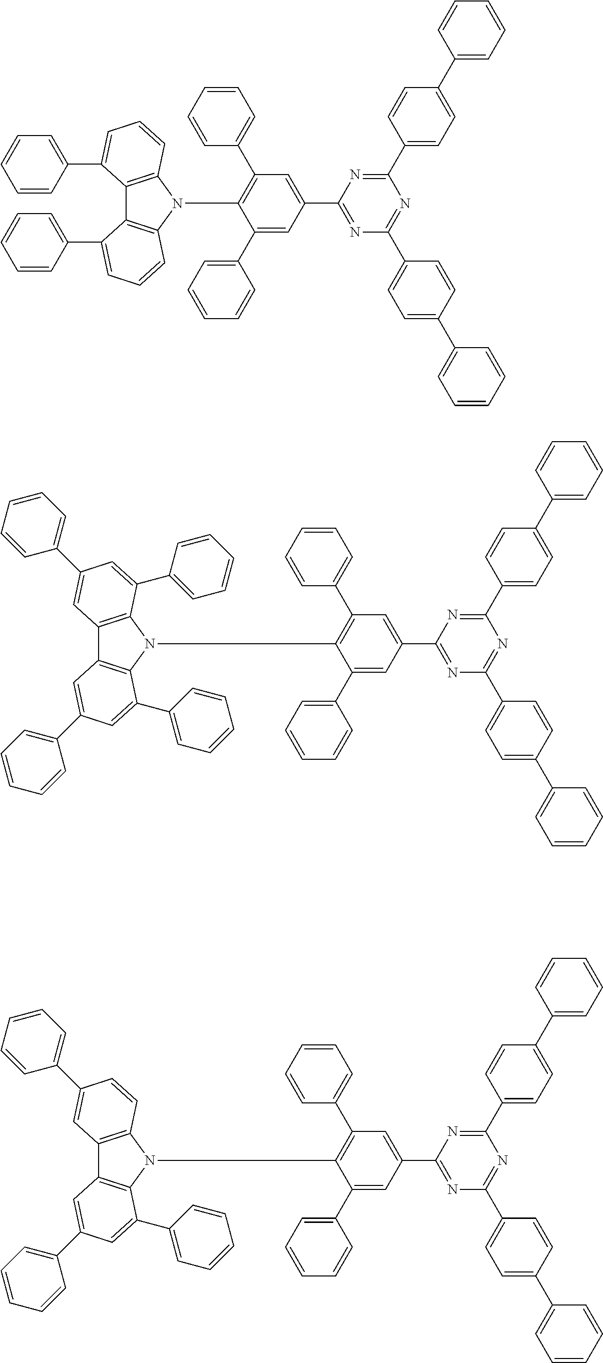 [SMILES: c1ccc(-c2ccc(-c3nc(-c4ccc(-c5ccccc5)cc4)nc(-c4cc(-c5ccccc5)c(-n5c6cccc(-c7ccccc7)c6c6c(-c7ccccc7)cccc65)c(-c5ccccc5)c4)n3)cc2)cc1 ; c1ccc(-c2ccc(-c3nc(-c4ccc(-c5ccccc5)cc4)nc(-c4cc(-c5ccccc5)c(-n5c6c(-c7ccccc7)cc(-c7ccccc7)cc6c6cc(-c7ccccc7)cc(-c7ccccc7)c65)c(-c5ccccc5)c4)n3)cc2)cc1 ; c1ccc(-c2ccc(-c3nc(-c4ccc(-c5ccccc5)cc4)nc(-c4cc(-c5ccccc5)c(-n5c6ccc(-c7ccccc7)cc6c6cc(-c7ccccc7)cc(-c7ccccc7)c65)c(-c5ccccc5)c4)n3)cc2)cc1]

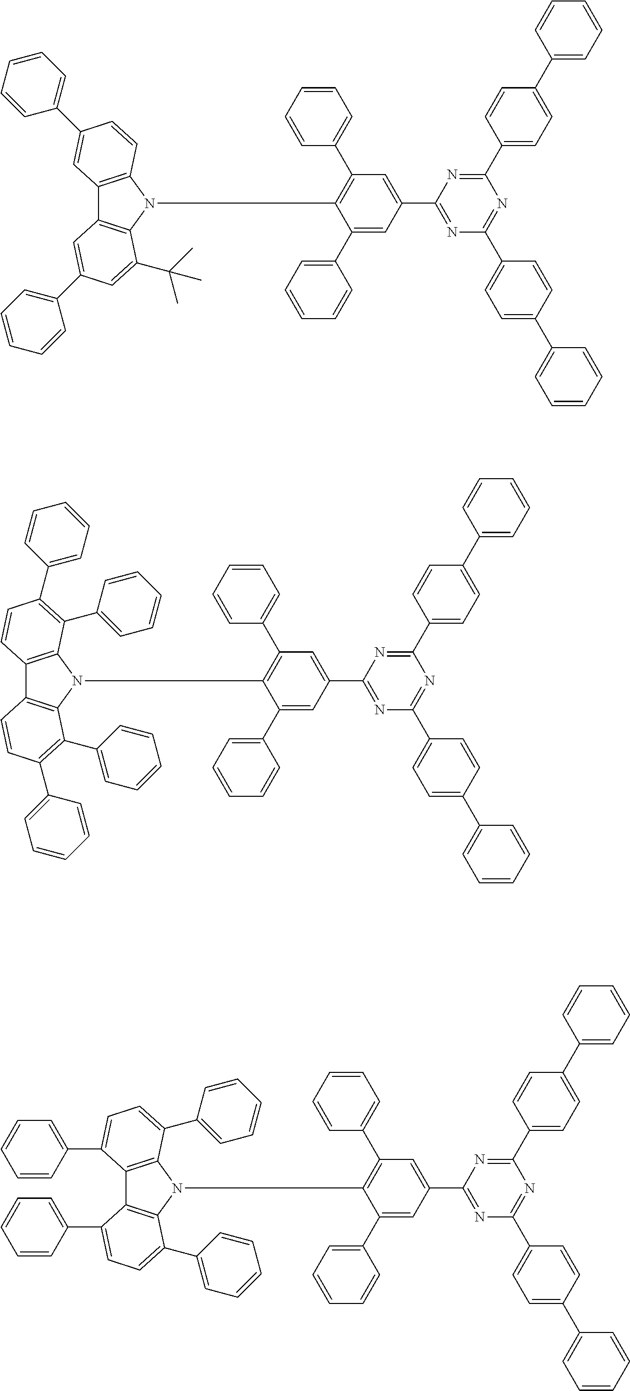 [SMILES: CC(C)(C)c1cc(-c2ccccc2)cc2c3cc(-c4ccccc4)ccc3n(-c3c(-c4ccccc4)cc(-c4nc(-c5ccc(-c6ccccc6)cc5)nc(-c5ccc(-c6ccccc6)cc5)n4)cc3-c3ccccc3)c12 ; c1ccc(-c2ccc(-c3nc(-c4ccc(-c5ccccc5)cc4)nc(-c4cc(-c5ccccc5)c(-n5c6c(-c7ccccc7)c(-c7ccccc7)ccc6c6ccc(-c7ccccc7)c(-c7ccccc7)c65)c(-c5ccccc5)c4)n3)cc2)cc1 ; c1ccc(-c2ccc(-c3nc(-c4ccc(-c5ccccc5)cc4)nc(-c4cc(-c5ccccc5)c(-n5c6c(-c7ccccc7)ccc(-c7ccccc7)c6c6c(-c7ccccc7)ccc(-c7ccccc7)c65)c(-c5ccccc5)c4)n3)cc2)cc1]

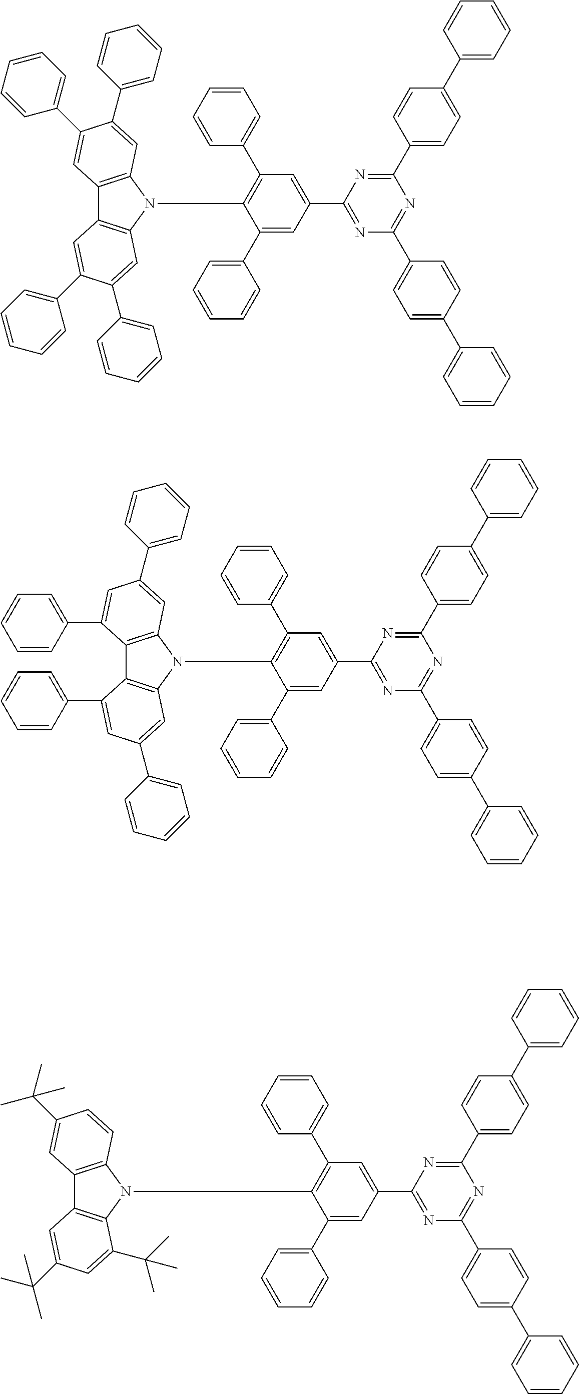 [SMILES: c1ccc(-c2ccc(-c3nc(-c4ccc(-c5ccccc5)cc4)nc(-c4cc(-c5ccccc5)c(-n5c6cc(-c7ccccc7)c(-c7ccccc7)cc6c6cc(-c7ccccc7)c(-c7ccccc7)cc65)c(-c5ccccc5)c4)n3)cc2)cc1 ; c1ccc(-c2ccc(-c3nc(-c4ccc(-c5ccccc5)cc4)nc(-c4cc(-c5ccccc5)c(-n5c6cc(-c7ccccc7)cc(-c7ccccc7)c6c6c(-c7ccccc7)cc(-c7ccccc7)cc65)c(-c5ccccc5)c4)n3)cc2)cc1 ; CC(C)(C)c1ccc2c(c1)c1cc(C(C)(C)C)cc(C(C)(C)C)c1n2-c1c(-c2ccccc2)cc(-c2nc(-c3ccc(-c4ccccc4)cc3)nc(-c3ccc(-c4ccccc4)cc3)n2)cc1-c1ccccc1]

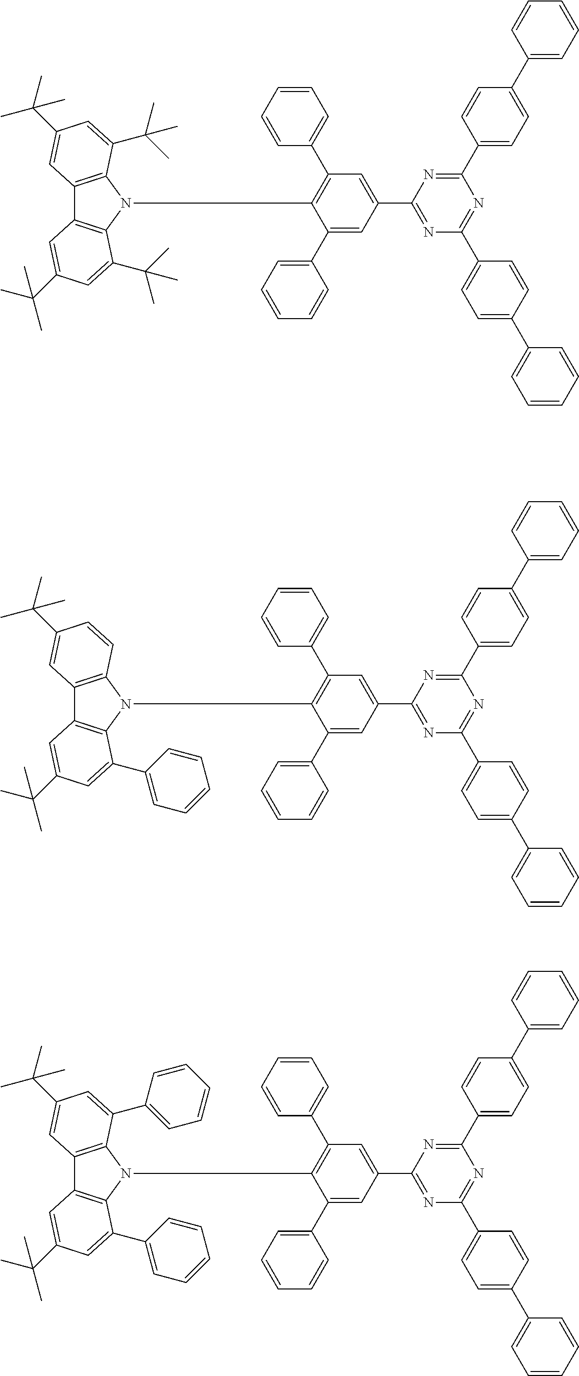 [SMILES: CC(C)(C)c1cc(C(C)(C)C)c2c(c1)c1cc(C(C)(C)C)cc(C(C)(C)C)c1n2-c1c(-c2ccccc2)cc(-c2nc(-c3ccc(-c4ccccc4)cc3)nc(-c3ccc(-c4ccccc4)cc3)n2)cc1-c1ccccc1 ; CC(C)(C)c1ccc2c(c1)c1cc(C(C)(C)C)cc(-c3ccccc3)c1n2-c1c(-c2ccccc2)cc(-c2nc(-c3ccc(-c4ccccc4)cc3)nc(-c3ccc(-c4ccccc4)cc3)n2)cc1-c1ccccc1 ; CC(C)(C)c1cc(-c2ccccc2)c2c(c1)c1cc(C(C)(C)C)cc(-c3ccccc3)c1n2-c1c(-c2ccccc2)cc(-c2nc(-c3ccc(-c4ccccc4)cc3)nc(-c3ccc(-c4ccccc4)cc3)n2)cc1-c1ccccc1]

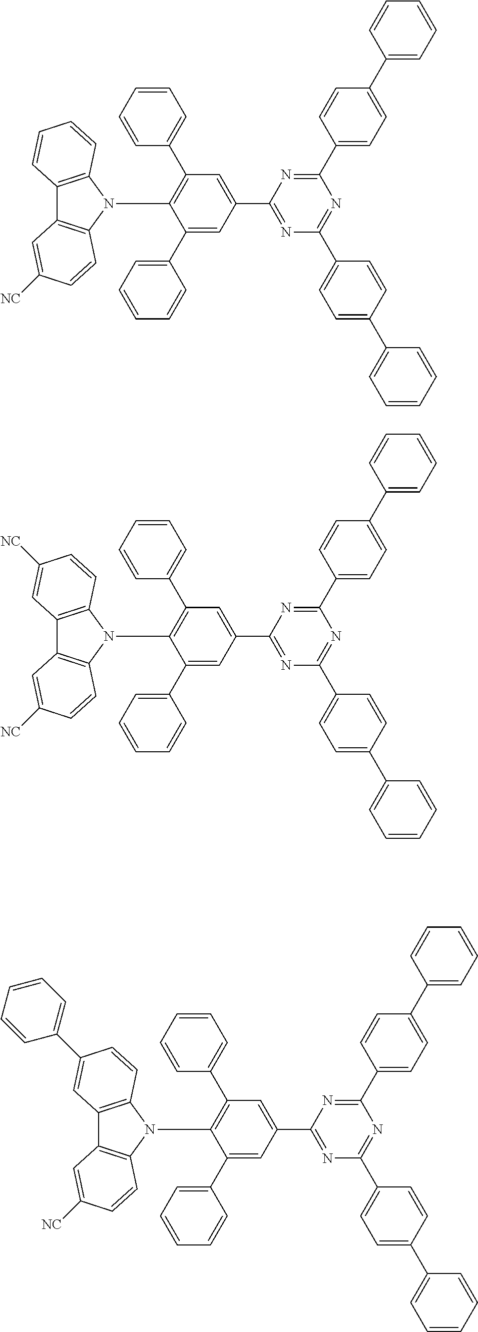

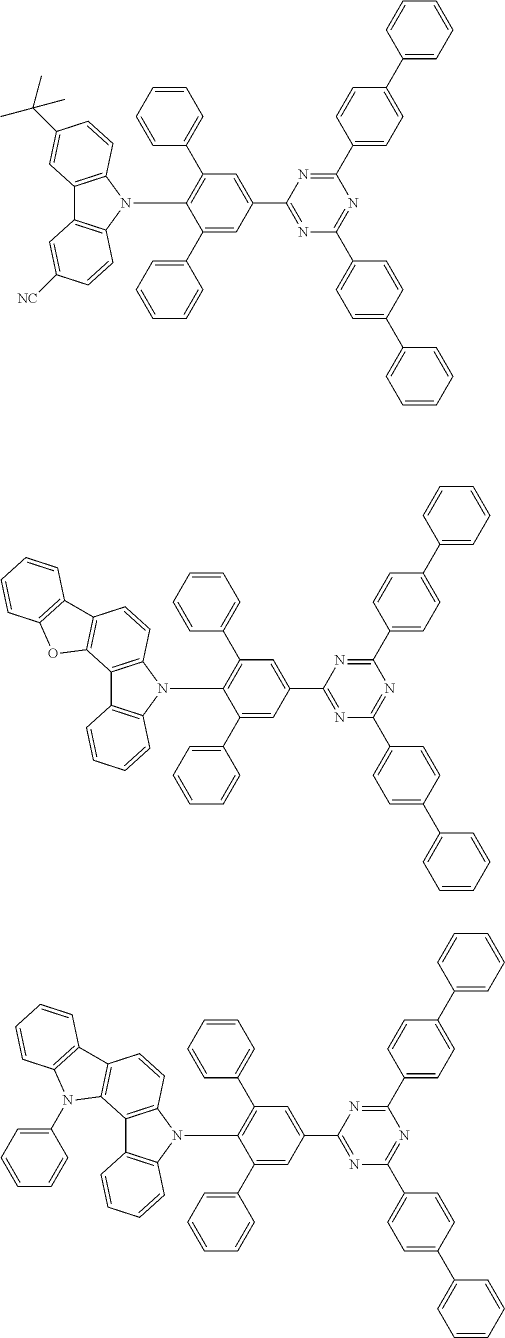

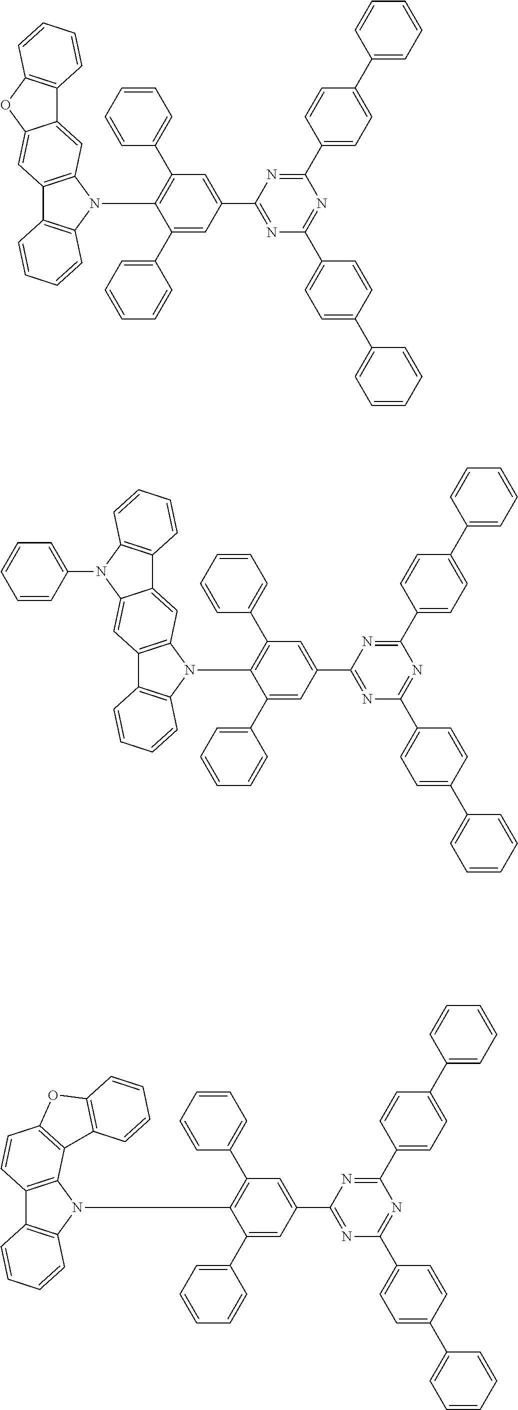 [SMILES: c1ccc(-c2ccc(-c3nc(-c4ccc(-c5ccccc5)cc4)nc(-c4cc(-c5ccccc5)c(-n5c6ccccc6c6cc7oc8ccccc8c7cc65)c(-c5ccccc5)c4)n3)cc2)cc1 ; c1ccc(-c2ccc(-c3nc(-c4ccc(-c5ccccc5)cc4)nc(-c4cc(-c5ccccc5)c(-n5c6ccccc6c6cc7c(cc65)c5ccccc5n7-c5ccccc5)c(-c5ccccc5)c4)n3)cc2)cc1 ; c1ccc(-c2ccc(-c3nc(-c4ccc(-c5ccccc5)cc4)nc(-c4cc(-c5ccccc5)c(-n5c6ccccc6c6ccc7oc8ccccc8c7c65)c(-c5ccccc5)c4)n3)cc2)cc1]

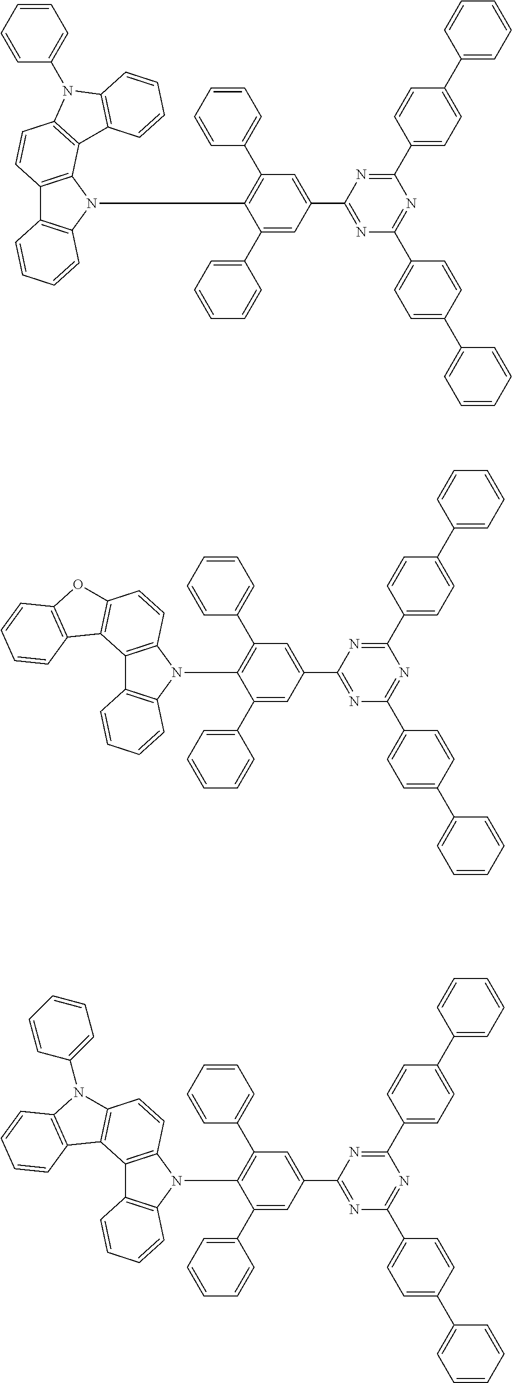 [SMILES: c1ccc(-c2ccc(-c3nc(-c4ccc(-c5ccccc5)cc4)nc(-c4cc(-c5ccccc5)c(-n5c6ccccc6c6ccc7c(c8ccccc8n7-c7ccccc7)c65)c(-c5ccccc5)c4)n3)cc2)cc1 ; c1ccc(-c2ccc(-c3nc(-c4ccc(-c5ccccc5)cc4)nc(-c4cc(-c5ccccc5)c(-n5c6ccccc6c6c7c(ccc65)oc5ccccc57)c(-c5ccccc5)c4)n3)cc2)cc1 ; c1ccc(-c2ccc(-c3nc(-c4ccc(-c5ccccc5)cc4)nc(-c4cc(-c5ccccc5)c(-n5c6ccccc6c6c7c8ccccc8n(-c8ccccc8)c7ccc65)c(-c5ccccc5)c4)n3)cc2)cc1]

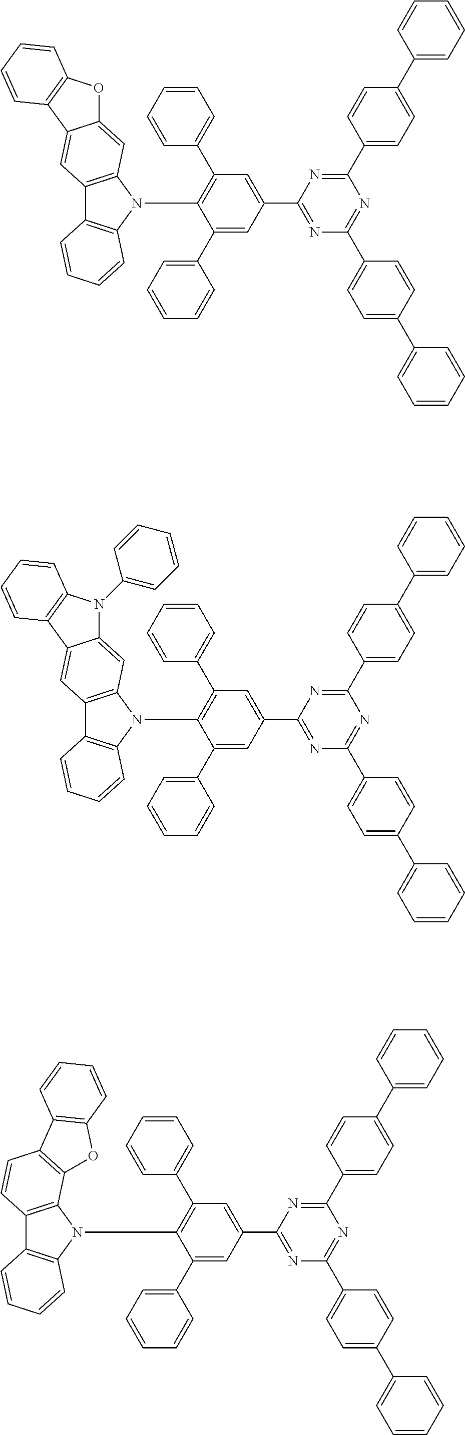 [SMILES: c1ccc(-c2ccc(-c3nc(-c4ccc(-c5ccccc5)cc4)nc(-c4cc(-c5ccccc5)c(-n5c6ccccc6c6cc7c(cc65)oc5ccccc57)c(-c5ccccc5)c4)n3)cc2)cc1 ; c1ccc(-c2ccc(-c3nc(-c4ccc(-c5ccccc5)cc4)nc(-c4cc(-c5ccccc5)c(-n5c6ccccc6c6cc7c8ccccc8n(-c8ccccc8)c7cc65)c(-c5ccccc5)c4)n3)cc2)cc1 ; c1ccc(-c2ccc(-c3nc(-c4ccc(-c5ccccc5)cc4)nc(-c4cc(-c5ccccc5)c(-n5c6ccccc6c6ccc7c8ccccc8oc7c65)c(-c5ccccc5)c4)n3)cc2)cc1]

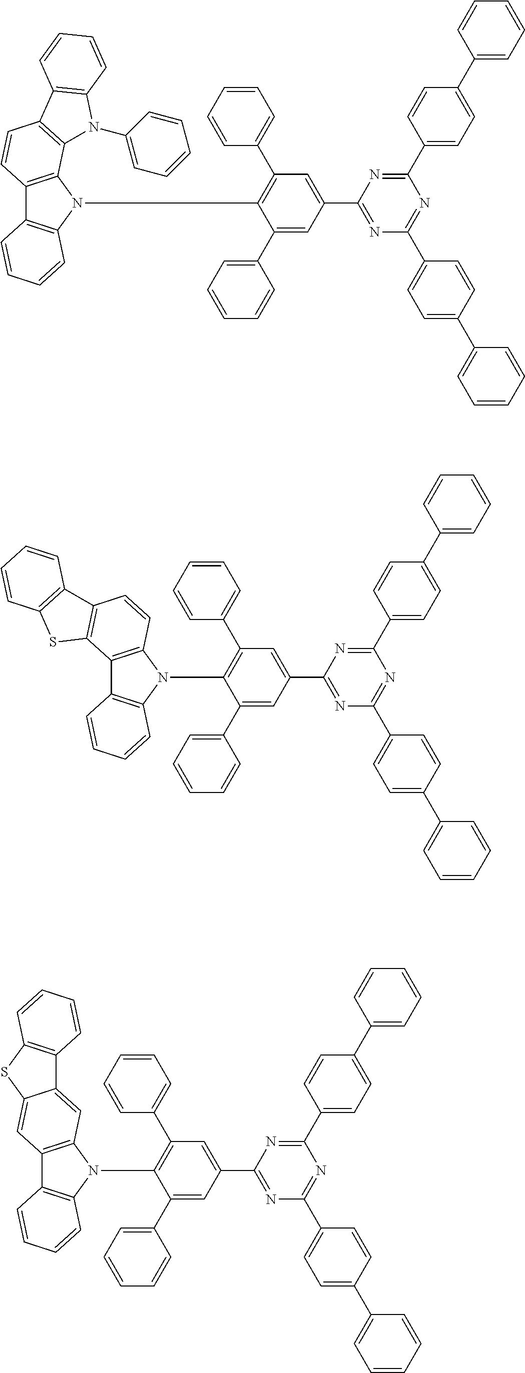 [SMILES: c1ccc(-c2ccc(-c3nc(-c4ccc(-c5ccccc5)cc4)nc(-c4cc(-c5ccccc5)c(-n5c6ccccc6c6ccc7c8ccccc8n(-c8ccccc8)c7c65)c(-c5ccccc5)c4)n3)cc2)cc1 ; c1ccc(-c2ccc(-c3nc(-c4ccc(-c5ccccc5)cc4)nc(-c4cc(-c5ccccc5)c(-n5c6ccccc6c6c7sc8ccccc8c7ccc65)c(-c5ccccc5)c4)n3)cc2)cc1 ; c1ccc(-c2ccc(-c3nc(-c4ccc(-c5ccccc5)cc4)nc(-c4cc(-c5ccccc5)c(-n5c6ccccc6c6cc7sc8ccccc8c7cc65)c(-c5ccccc5)c4)n3)cc2)cc1]

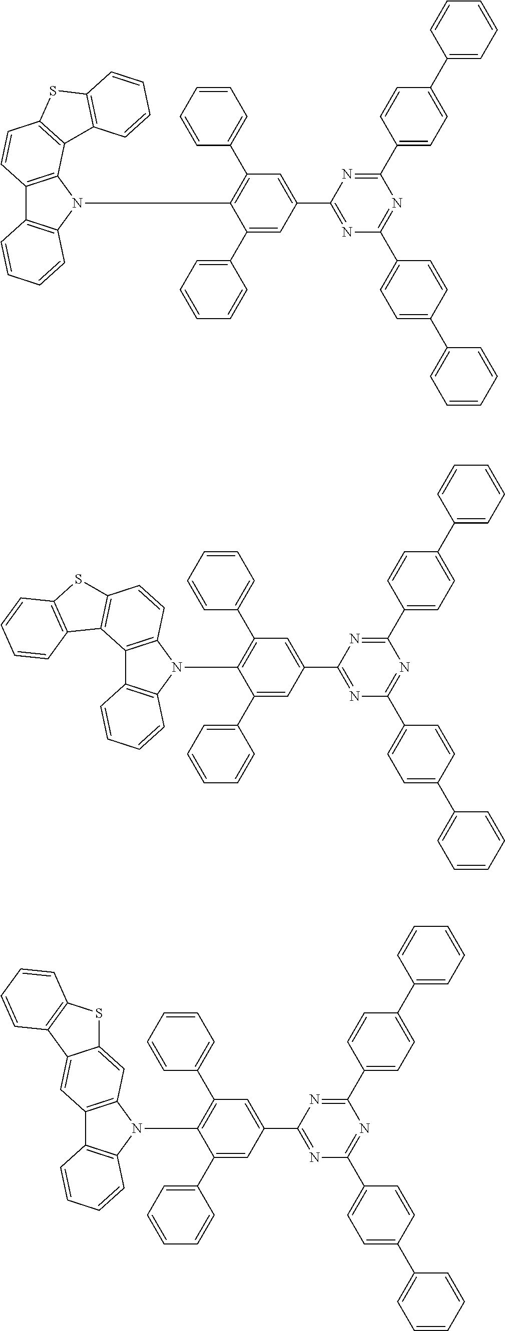 [SMILES: c1ccc(-c2ccc(-c3nc(-c4ccc(-c5ccccc5)cc4)nc(-c4cc(-c5ccccc5)c(-n5c6ccccc6c6ccc7sc8ccccc8c7c65)c(-c5ccccc5)c4)n3)cc2)cc1 ; c1ccc(-c2ccc(-c3nc(-c4ccc(-c5ccccc5)cc4)nc(-c4cc(-c5ccccc5)c(-n5c6ccccc6c6c7c(ccc65)sc5ccccc57)c(-c5ccccc5)c4)n3)cc2)cc1 ; c1ccc(-c2ccc(-c3nc(-c4ccc(-c5ccccc5)cc4)nc(-c4cc(-c5ccccc5)c(-n5c6ccccc6c6cc7c(cc65)sc5ccccc57)c(-c5ccccc5)c4)n3)cc2)cc1]

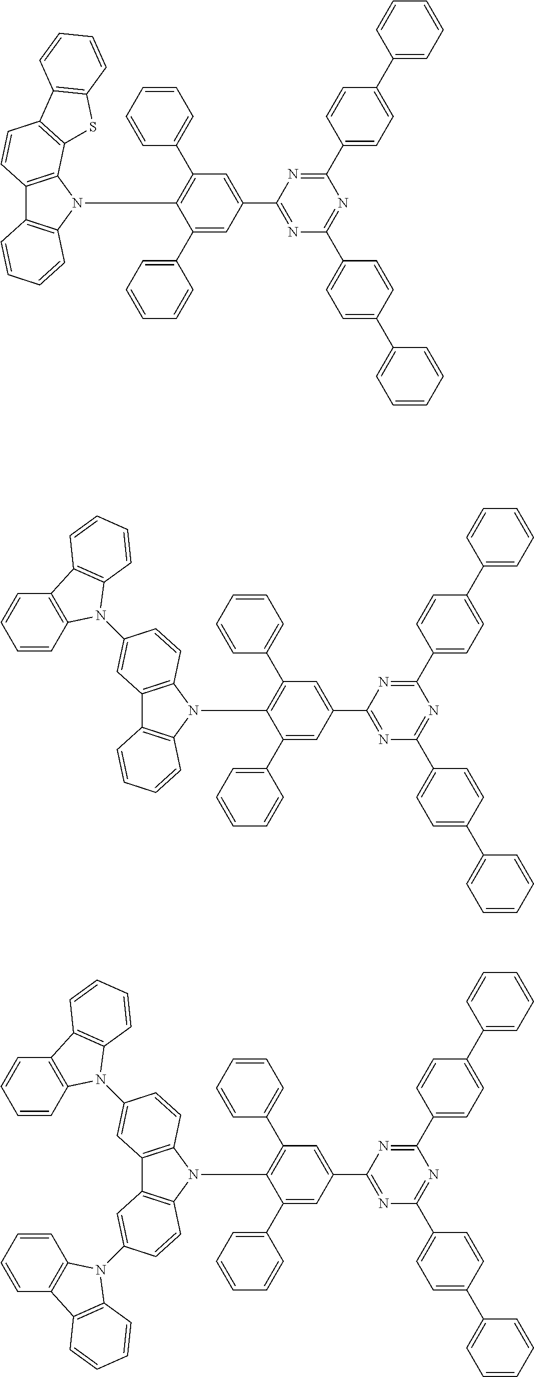 [SMILES: c1ccc(-c2ccc(-c3nc(-c4ccc(-c5ccccc5)cc4)nc(-c4cc(-c5ccccc5)c(-n5c6ccccc6c6ccc7c8ccccc8sc7c65)c(-c5ccccc5)c4)n3)cc2)cc1 ; c1ccc(-c2ccc(-c3nc(-c4ccc(-c5ccccc5)cc4)nc(-c4cc(-c5ccccc5)c(-n5c6ccccc6c6cc(-n7c8ccccc8c8ccccc87)ccc65)c(-c5ccccc5)c4)n3)cc2)cc1 ; c1ccc(-c2ccc(-c3nc(-c4ccc(-c5ccccc5)cc4)nc(-c4cc(-c5ccccc5)c(-n5c6ccc(-n7c8ccccc8c8ccccc87)cc6c6cc(-n7c8ccccc8c8ccccc87)ccc65)c(-c5ccccc5)c4)n3)cc2)cc1]

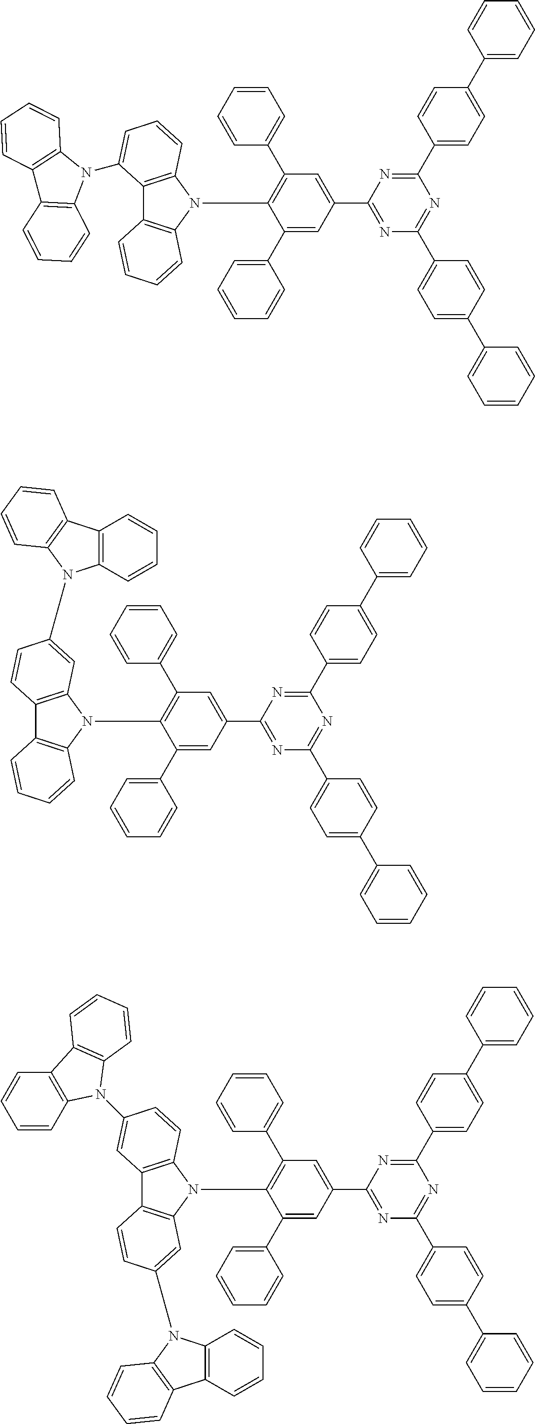 [SMILES: c1ccc(-c2ccc(-c3nc(-c4ccc(-c5ccccc5)cc4)nc(-c4cc(-c5ccccc5)c(-n5c6ccccc6c6c(-n7c8ccccc8c8ccccc87)cccc65)c(-c5ccccc5)c4)n3)cc2)cc1 ; c1ccc(-c2ccc(-c3nc(-c4ccc(-c5ccccc5)cc4)nc(-c4cc(-c5ccccc5)c(-n5c6ccccc6c6ccc(-n7c8ccccc8c8ccccc87)cc65)c(-c5ccccc5)c4)n3)cc2)cc1 ; c1ccc(-c2ccc(-c3nc(-c4ccc(-c5ccccc5)cc4)nc(-c4cc(-c5ccccc5)c(-n5c6ccc(-n7c8ccccc8c8ccccc87)cc6c6ccc(-n7c8ccccc8c8ccccc87)cc65)c(-c5ccccc5)c4)n3)cc2)cc1]

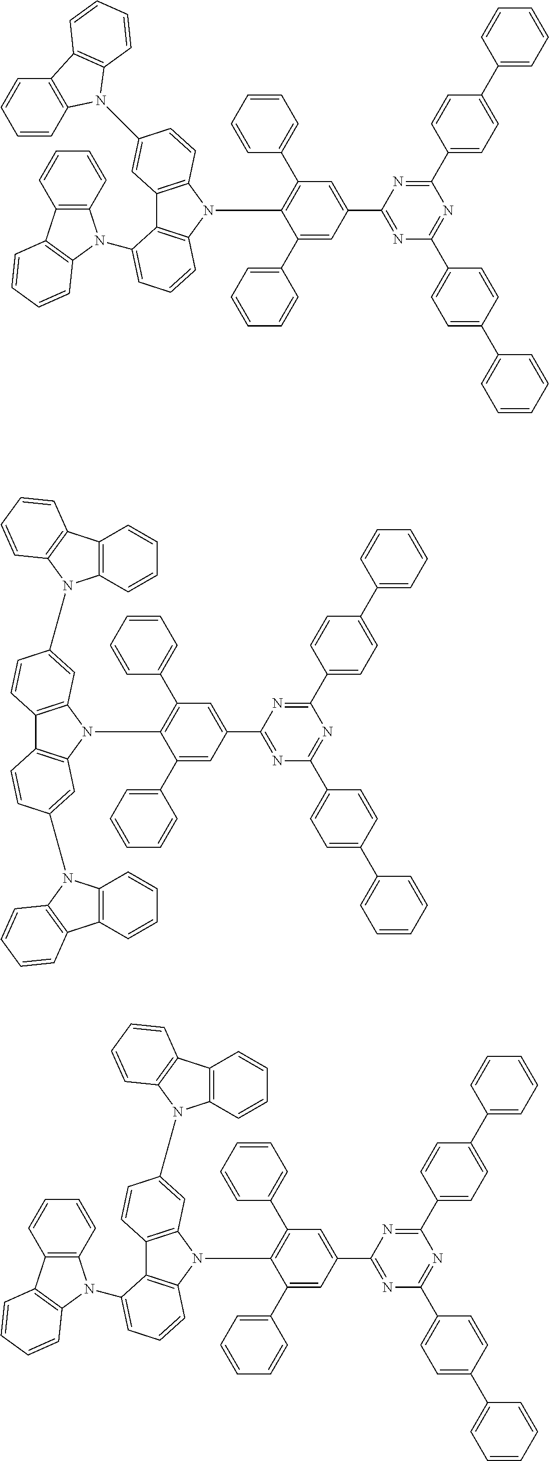 [SMILES: c1ccc(-c2ccc(-c3nc(-c4ccc(-c5ccccc5)cc4)nc(-c4cc(-c5ccccc5)c(-n5c6ccc(-n7c8ccccc8c8ccccc87)cc6c6c(-n7c8ccccc8c8ccccc87)cccc65)c(-c5ccccc5)c4)n3)cc2)cc1 ; c1ccc(-c2ccc(-c3nc(-c4ccc(-c5ccccc5)cc4)nc(-c4cc(-c5ccccc5)c(-n5c6cc(-n7c8ccccc8c8ccccc87)ccc6c6ccc(-n7c8ccccc8c8ccccc87)cc65)c(-c5ccccc5)c4)n3)cc2)cc1 ; c1ccc(-c2ccc(-c3nc(-c4ccc(-c5ccccc5)cc4)nc(-c4cc(-c5ccccc5)c(-n5c6cc(-n7c8ccccc8c8ccccc87)ccc6c6c(-n7c8ccccc8c8ccccc87)cccc65)c(-c5ccccc5)c4)n3)cc2)cc1]

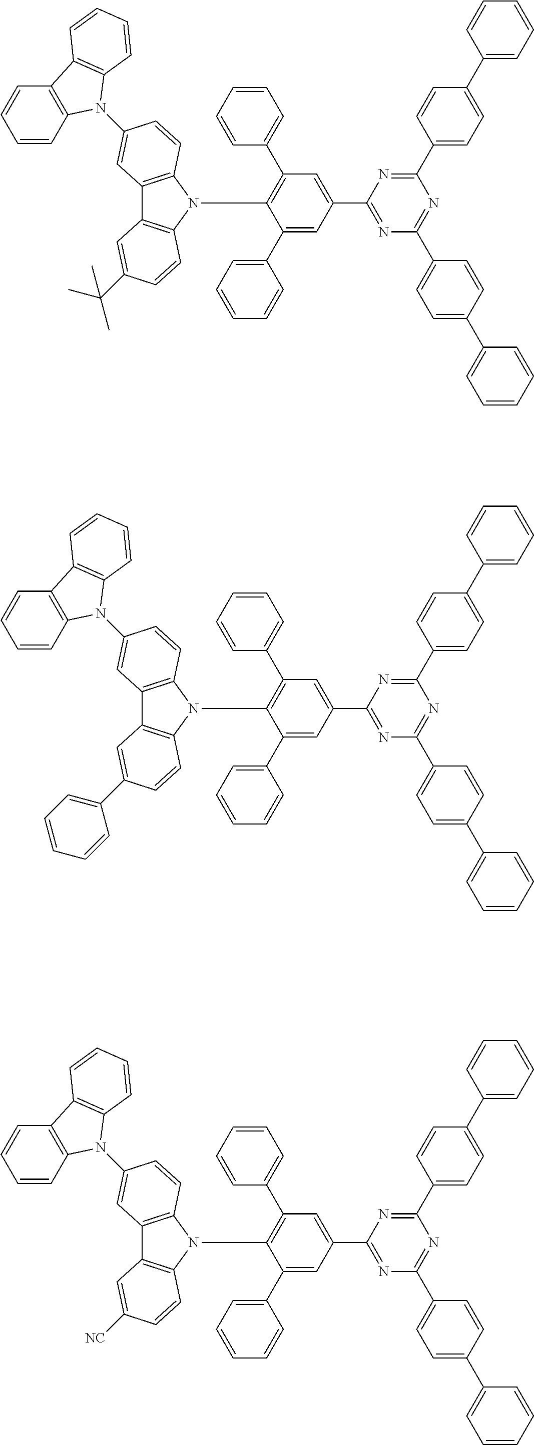 [SMILES: CC(C)(C)c1ccc2c(c1)c1cc(-n3c4ccccc4c4ccccc43)ccc1n2-c1c(-c2ccccc2)cc(-c2nc(-c3ccc(-c4ccccc4)cc3)nc(-c3ccc(-c4ccccc4)cc3)n2)cc1-c1ccccc1 ; c1ccc(-c2ccc(-c3nc(-c4ccc(-c5ccccc5)cc4)nc(-c4cc(-c5ccccc5)c(-n5c6ccc(-c7ccccc7)cc6c6cc(-n7c8ccccc8c8ccccc87)ccc65)c(-c5ccccc5)c4)n3)cc2)cc1 ; N#Cc1ccc2c(c1)c1cc(-n3c4ccccc4c4ccccc43)ccc1n2-c1c(-c2ccccc2)cc(-c2nc(-c3ccc(-c4ccccc4)cc3)nc(-c3ccc(-c4ccccc4)cc3)n2)cc1-c1ccccc1]

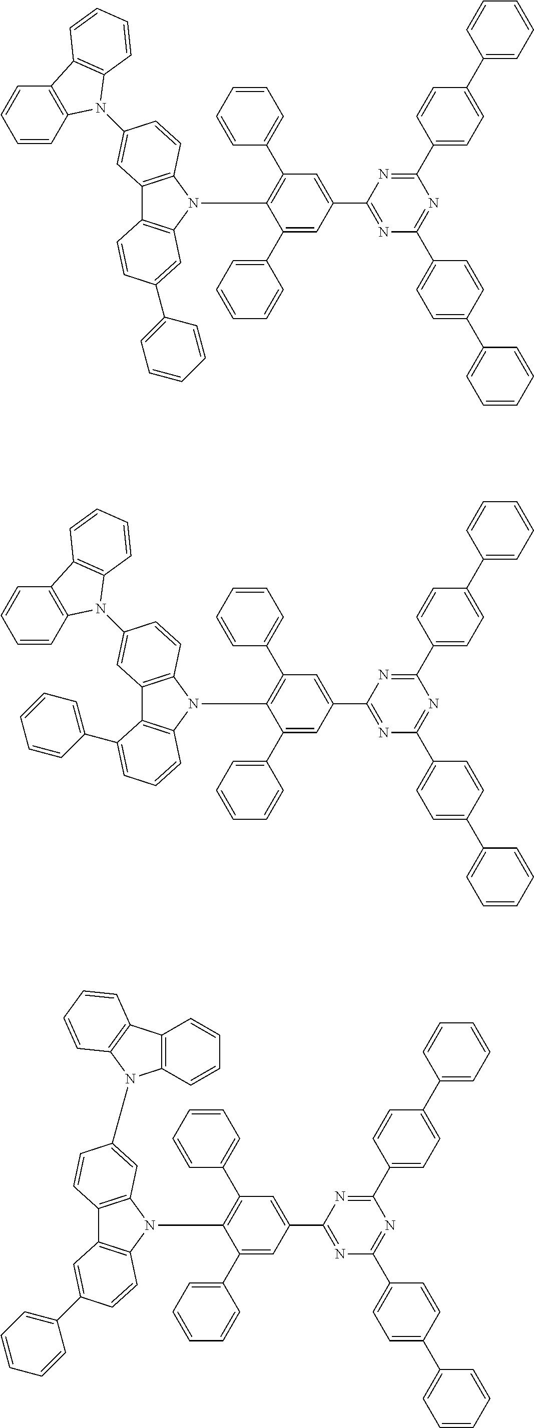 [SMILES: c1ccc(-c2ccc(-c3nc(-c4ccc(-c5ccccc5)cc4)nc(-c4cc(-c5ccccc5)c(-n5c6ccc(-n7c8ccccc8c8ccccc87)cc6c6ccc(-c7ccccc7)cc65)c(-c5ccccc5)c4)n3)cc2)cc1 ; c1ccc(-c2ccc(-c3nc(-c4ccc(-c5ccccc5)cc4)nc(-c4cc(-c5ccccc5)c(-n5c6ccc(-n7c8ccccc8c8ccccc87)cc6c6c(-c7ccccc7)cccc65)c(-c5ccccc5)c4)n3)cc2)cc1 ; c1ccc(-c2ccc(-c3nc(-c4ccc(-c5ccccc5)cc4)nc(-c4cc(-c5ccccc5)c(-n5c6ccc(-c7ccccc7)cc6c6ccc(-n7c8ccccc8c8ccccc87)cc65)c(-c5ccccc5)c4)n3)cc2)cc1]

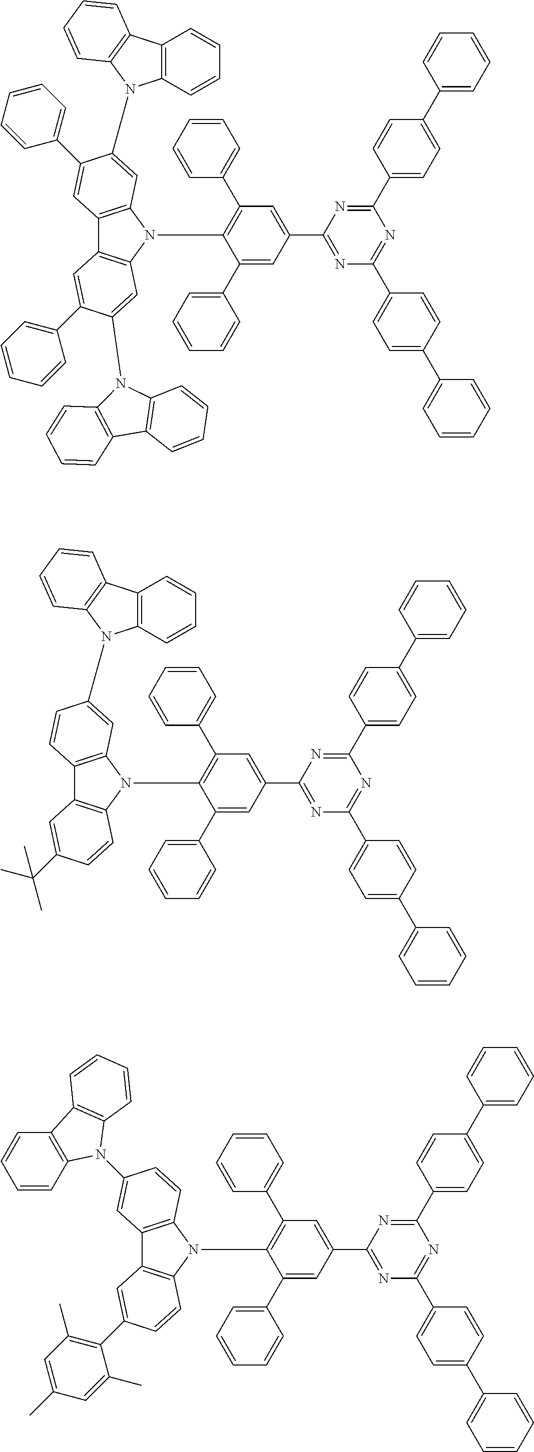 [SMILES: c1ccc(-c2ccc(-c3nc(-c4ccc(-c5ccccc5)cc4)nc(-c4cc(-c5ccccc5)c(-n5c6cc(-n7c8ccccc8c8ccccc87)c(-c7ccccc7)cc6c6cc(-c7ccccc7)c(-n7c8ccccc8c8ccccc87)cc65)c(-c5ccccc5)c4)n3)cc2)cc1 ; CC(C)(C)c1ccc2c(c1)c1ccc(-n3c4ccccc4c4ccccc43)cc1n2-c1c(-c2ccccc2)cc(-c2nc(-c3ccc(-c4ccccc4)cc3)nc(-c3ccc(-c4ccccc4)cc3)n2)cc1-c1ccccc1 ; Cc1cc(C)c(-c2ccc3c(c2)c2cc(-n4c5ccccc5c5ccccc54)ccc2n3-c2c(-c3ccccc3)cc(-c3nc(-c4ccc(-c5ccccc5)cc4)nc(-c4ccc(-c5ccccc5)cc4)n3)cc2-c2ccccc2)c(C)c1]

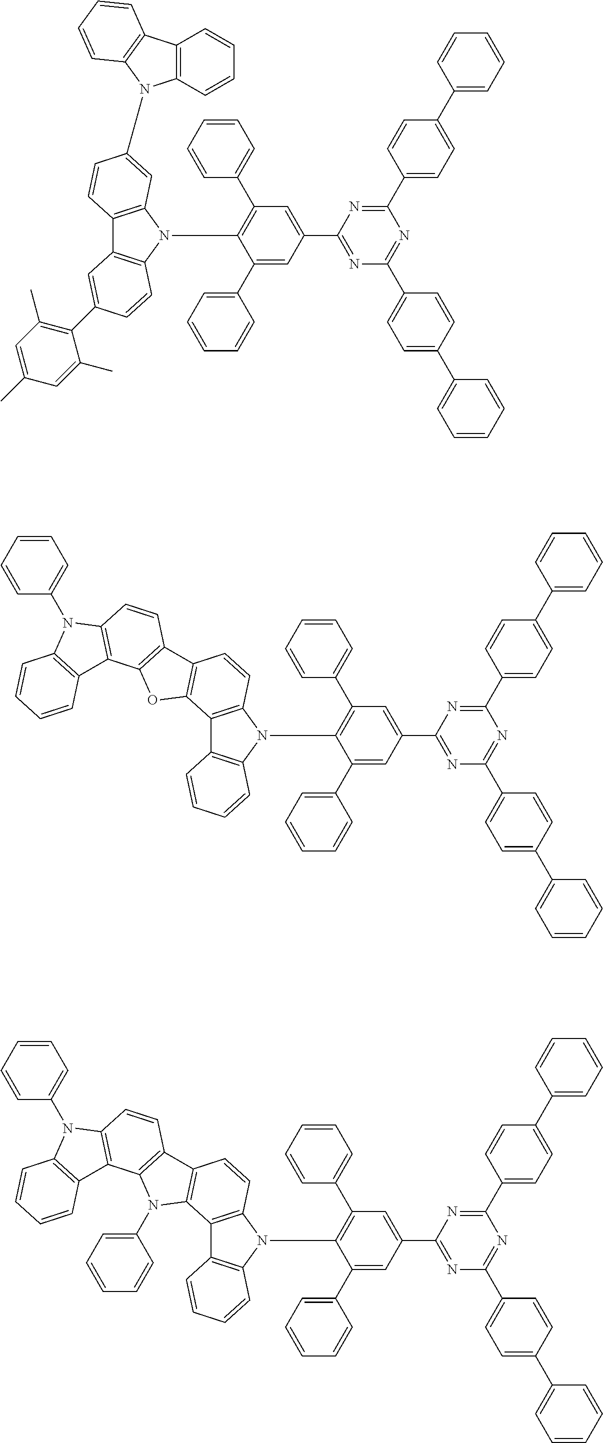 [SMILES: Cc1cc(C)c(-c2ccc3c(c2)c2ccc(-n4c5ccccc5c5ccccc54)cc2n3-c2c(-c3ccccc3)cc(-c3nc(-c4ccc(-c5ccccc5)cc4)nc(-c4ccc(-c5ccccc5)cc4)n3)cc2-c2ccccc2)c(C)c1 ; c1ccc(-c2ccc(-c3nc(-c4ccc(-c5ccccc5)cc4)nc(-c4cc(-c5ccccc5)c(-n5c6ccccc6c6c7oc8c(ccc9c8c8ccccc8n9-c8ccccc8)c7ccc65)c(-c5ccccc5)c4)n3)cc2)cc1 ; c1ccc(-c2ccc(-c3nc(-c4ccc(-c5ccccc5)cc4)nc(-c4cc(-c5ccccc5)c(-n5c6ccccc6c6c5ccc5c7ccc8c(c9ccccc9n8-c8ccccc8)c7n(-c7ccccc7)c56)c(-c5ccccc5)c4)n3)cc2)cc1]

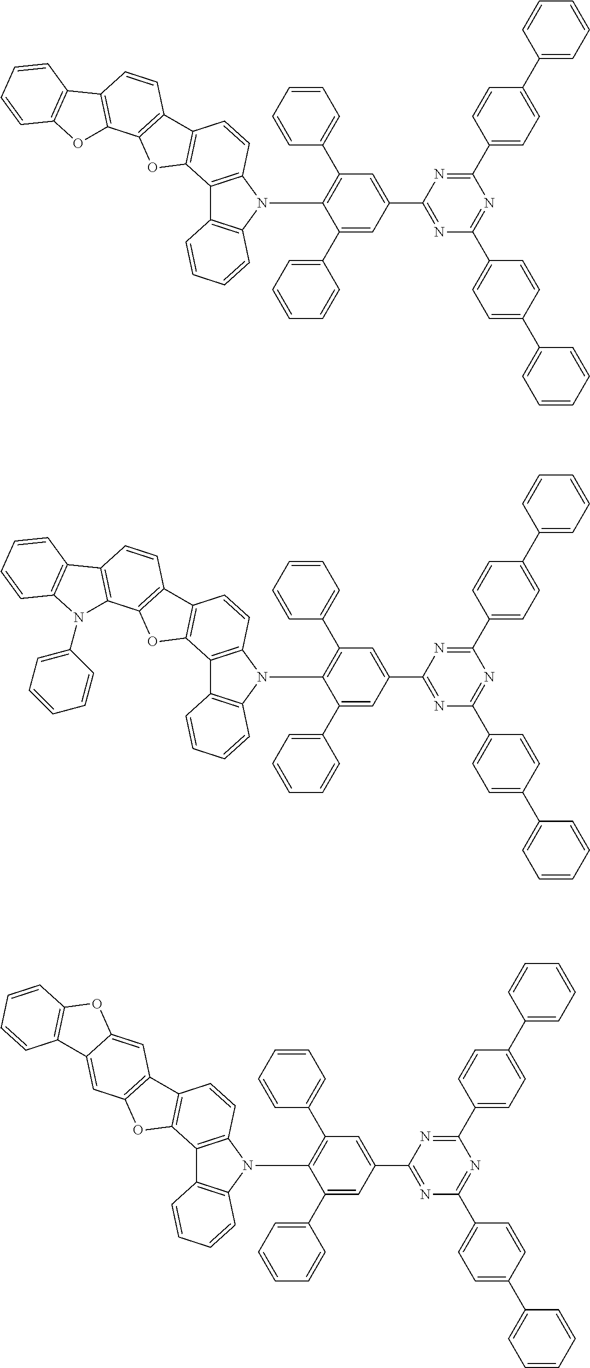 [SMILES: c1ccc(-c2ccc(-c3nc(-c4ccc(-c5ccccc5)cc4)nc(-c4cc(-c5ccccc5)c(-n5c6ccccc6c6c7oc8c(ccc9c%10ccccc%10oc98)c7ccc65)c(-c5ccccc5)c4)n3)cc2)cc1 ; c1ccc(-c2ccc(-c3nc(-c4ccc(-c5ccccc5)cc4)nc(-c4cc(-c5ccccc5)c(-n5c6ccccc6c6c7oc8c(ccc9c%10ccccc%10n(-c%10ccccc%10)c98)c7ccc65)c(-c5ccccc5)c4)n3)cc2)cc1 ; c1ccc(-c2ccc(-c3nc(-c4ccc(-c5ccccc5)cc4)nc(-c4cc(-c5ccccc5)c(-n5c6ccccc6c6c7oc8cc9c(cc8c7ccc65)oc5ccccc59)c(-c5ccccc5)c4)n3)cc2)cc1]

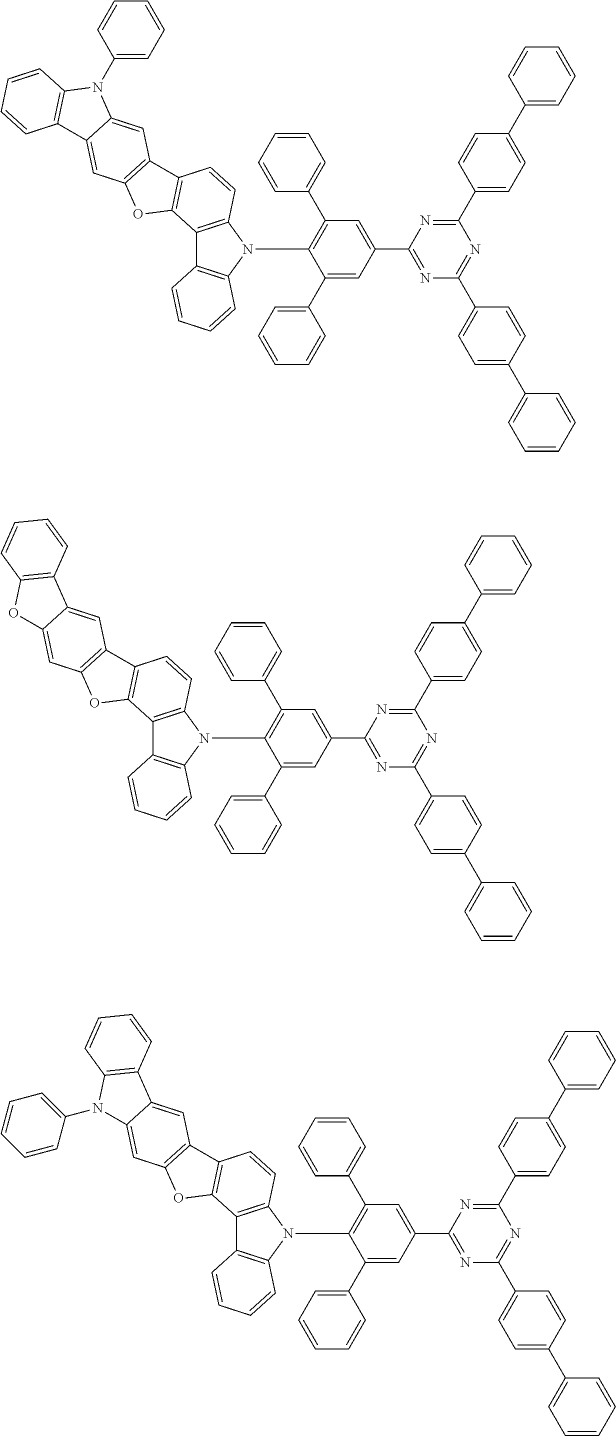 [SMILES: c1ccc(-c2ccc(-c3nc(-c4ccc(-c5ccccc5)cc4)nc(-c4cc(-c5ccccc5)c(-n5c6ccccc6c6c7oc8cc9c%10ccccc%10n(-c%10ccccc%10)c9cc8c7ccc65)c(-c5ccccc5)c4)n3)cc2)cc1 ; c1ccc(-c2ccc(-c3nc(-c4ccc(-c5ccccc5)cc4)nc(-c4cc(-c5ccccc5)c(-n5c6ccccc6c6c7oc8cc9oc%10ccccc%10c9cc8c7ccc65)c(-c5ccccc5)c4)n3)cc2)cc1 ; c1ccc(-c2ccc(-c3nc(-c4ccc(-c5ccccc5)cc4)nc(-c4cc(-c5ccccc5)c(-n5c6ccccc6c6c7oc8cc9c(cc8c7ccc65)c5ccccc5n9-c5ccccc5)c(-c5ccccc5)c4)n3)cc2)cc1]

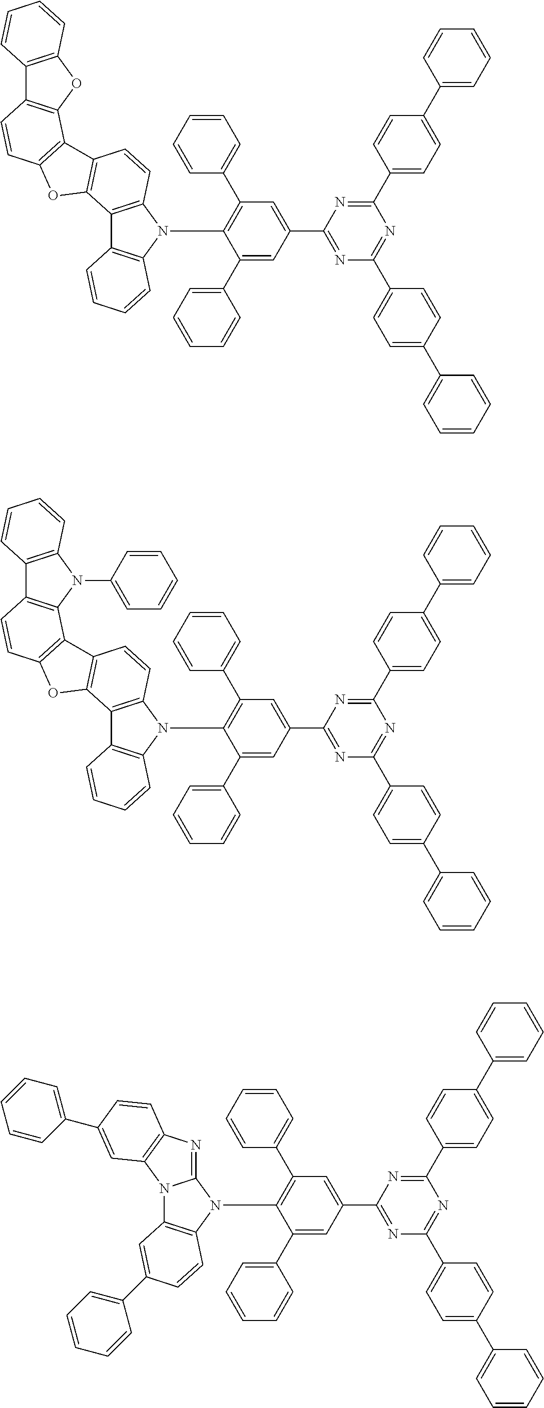 [SMILES: c1ccc(-c2ccc(-c3nc(-c4ccc(-c5ccccc5)cc4)nc(-c4cc(-c5ccccc5)c(-n5c6ccccc6c6c7oc8ccc9c%10ccccc%10oc9c8c7ccc65)c(-c5ccccc5)c4)n3)cc2)cc1 ; c1ccc(-c2ccc(-c3nc(-c4ccc(-c5ccccc5)cc4)nc(-c4cc(-c5ccccc5)c(-n5c6ccccc6c6c7oc8ccc9c%10ccccc%10n(-c%10ccccc%10)c9c8c7ccc65)c(-c5ccccc5)c4)n3)cc2)cc1 ; c1ccc(-c2ccc(-c3nc(-c4ccc(-c5ccccc5)cc4)nc(-c4cc(-c5ccccc5)c(-n5c6ccc(-c7ccccc7)cc6n6c7cc(-c8ccccc8)ccc7nc56)c(-c5ccccc5)c4)n3)cc2)cc1]

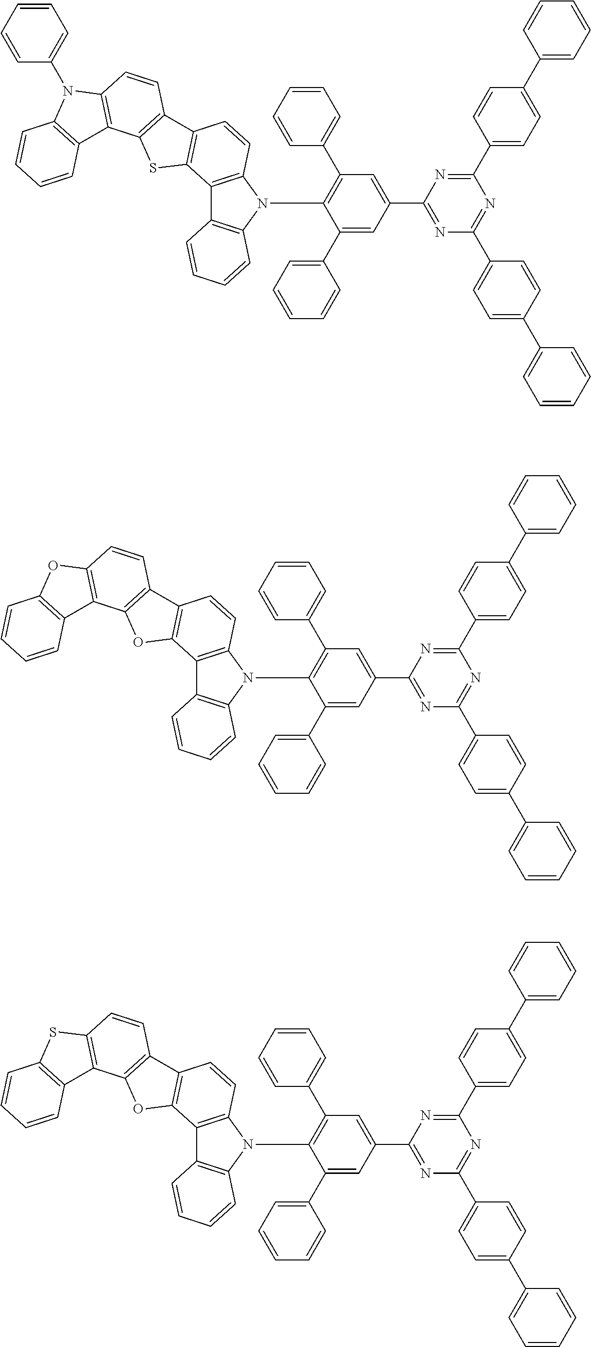 [SMILES: c1ccc(-c2ccc(-c3nc(-c4ccc(-c5ccccc5)cc4)nc(-c4cc(-c5ccccc5)c(-n5c6ccccc6c6c7sc8c(ccc9c8c8ccccc8n9-c8ccccc8)c7ccc65)c(-c5ccccc5)c4)n3)cc2)cc1 ; c1ccc(-c2ccc(-c3nc(-c4ccc(-c5ccccc5)cc4)nc(-c4cc(-c5ccccc5)c(-n5c6ccccc6c6c7oc8c(ccc9oc%10ccccc%10c98)c7ccc65)c(-c5ccccc5)c4)n3)cc2)cc1 ; c1ccc(-c2ccc(-c3nc(-c4ccc(-c5ccccc5)cc4)nc(-c4cc(-c5ccccc5)c(-n5c6ccccc6c6c7oc8c(ccc9sc%10ccccc%10c98)c7ccc65)c(-c5ccccc5)c4)n3)cc2)cc1]

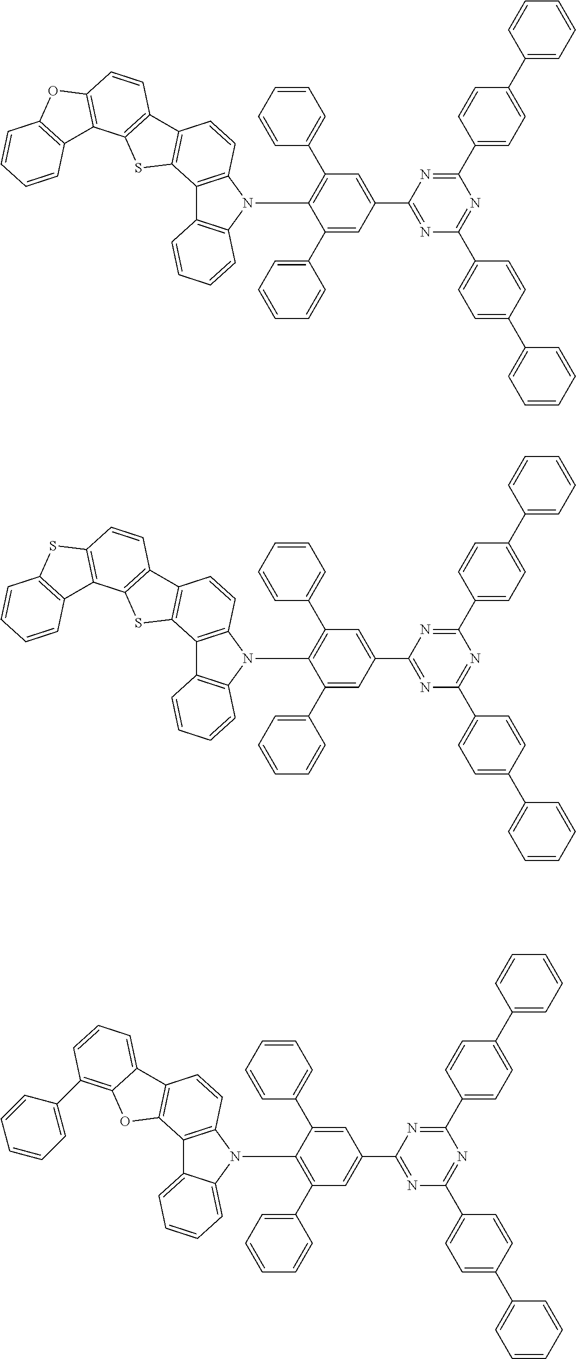 [SMILES: c1ccc(-c2ccc(-c3nc(-c4ccc(-c5ccccc5)cc4)nc(-c4cc(-c5ccccc5)c(-n5c6ccccc6c6c7sc8c(ccc9oc%10ccccc%10c98)c7ccc65)c(-c5ccccc5)c4)n3)cc2)cc1 ; c1ccc(-c2ccc(-c3nc(-c4ccc(-c5ccccc5)cc4)nc(-c4cc(-c5ccccc5)c(-n5c6ccccc6c6c7sc8c(ccc9sc%10ccccc%10c98)c7ccc65)c(-c5ccccc5)c4)n3)cc2)cc1 ; c1ccc(-c2ccc(-c3nc(-c4ccc(-c5ccccc5)cc4)nc(-c4cc(-c5ccccc5)c(-n5c6ccccc6c6c7oc8c(-c9ccccc9)cccc8c7ccc65)c(-c5ccccc5)c4)n3)cc2)cc1]

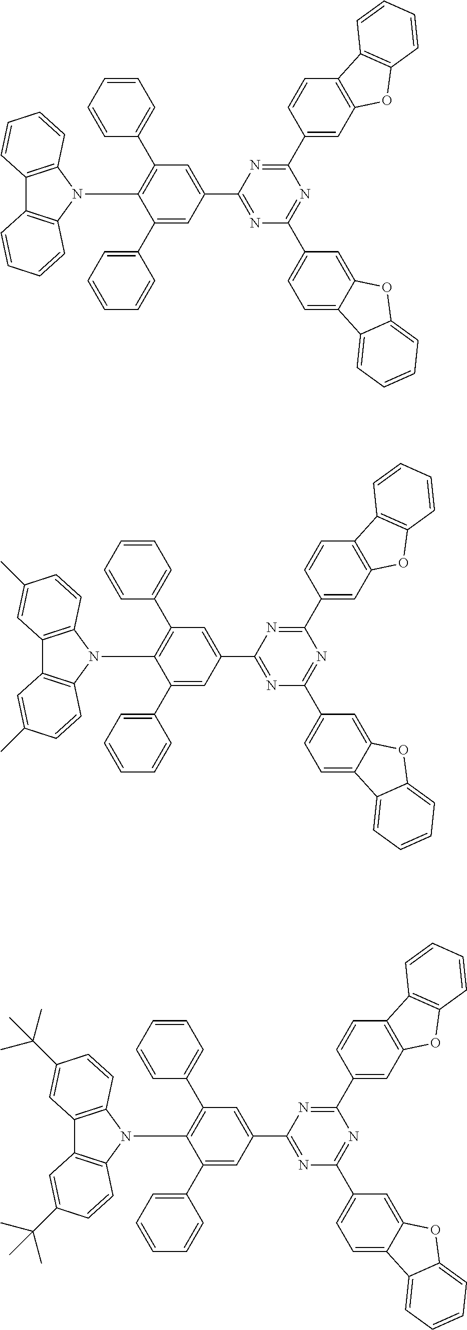 [SMILES: c1ccc(-c2cc(-c3nc(-c4ccc5c(c4)oc4ccccc45)nc(-c4ccc5c(c4)oc4ccccc45)n3)cc(-c3ccccc3)c2-n2c3ccccc3c3ccccc32)cc1 ; Cc1ccc2c(c1)c1cc(C)ccc1n2-c1c(-c2ccccc2)cc(-c2nc(-c3ccc4c(c3)oc3ccccc34)nc(-c3ccc4c(c3)oc3ccccc34)n2)cc1-c1ccccc1 ; CC(C)(C)c1ccc2c(c1)c1cc(C(C)(C)C)ccc1n2-c1c(-c2ccccc2)cc(-c2nc(-c3ccc4c(c3)oc3ccccc34)nc(-c3ccc4c(c3)oc3ccccc34)n2)cc1-c1ccccc1]

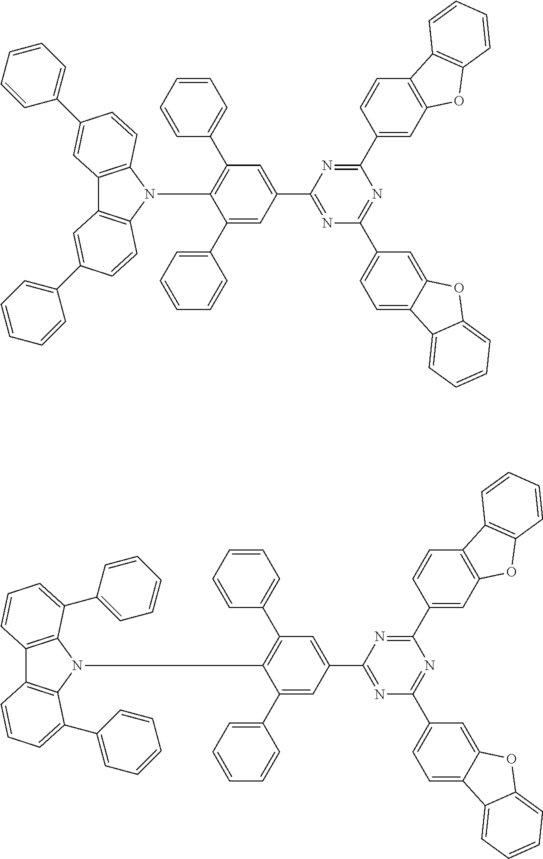 [SMILES: c1ccc(-c2ccc3c(c2)c2cc(-c4ccccc4)ccc2n3-c2c(-c3ccccc3)cc(-c3nc(-c4ccc5c(c4)oc4ccccc45)nc(-c4ccc5c(c4)oc4ccccc45)n3)cc2-c2ccccc2)cc1 ; c1ccc(-c2cc(-c3nc(-c4ccc5c(c4)oc4ccccc45)nc(-c4ccc5c(c4)oc4ccccc45)n3)cc(-c3ccccc3)c2-n2c3c(-c4ccccc4)cccc3c3cccc(-c4ccccc4)c32)cc1]

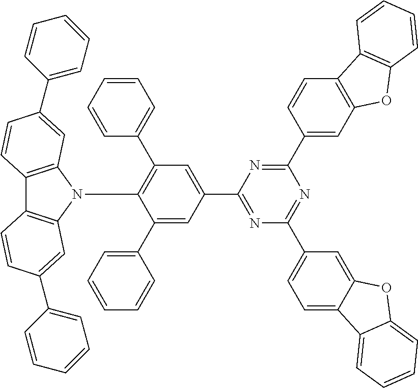 [SMILES: c1ccc(-c2ccc3c4ccc(-c5ccccc5)cc4n(-c4c(-c5ccccc5)cc(-c5nc(-c6ccc7c(c6)oc6ccccc67)nc(-c6ccc7c(c6)oc6ccccc67)n5)cc4-c4ccccc4)c3c2)cc1]

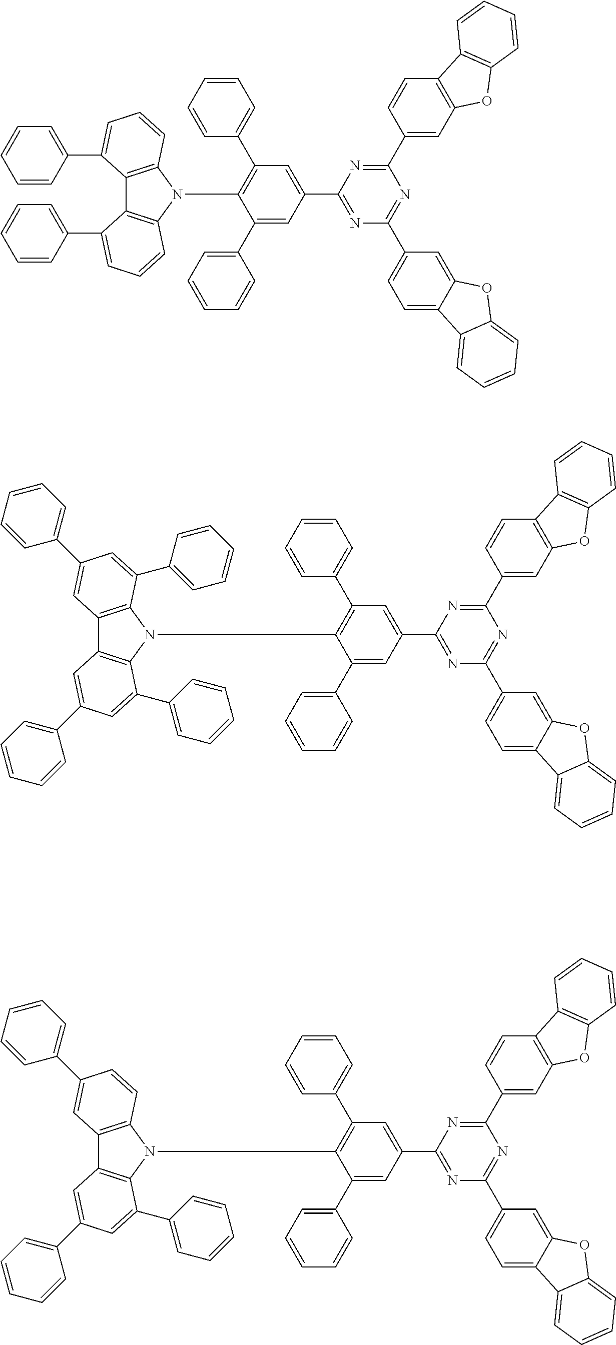 [SMILES: c1ccc(-c2cc(-c3nc(-c4ccc5c(c4)oc4ccccc45)nc(-c4ccc5c(c4)oc4ccccc45)n3)cc(-c3ccccc3)c2-n2c3cccc(-c4ccccc4)c3c3c(-c4ccccc4)cccc32)cc1 ; c1ccc(-c2cc(-c3ccccc3)c3c(c2)c2cc(-c4ccccc4)cc(-c4ccccc4)c2n3-c2c(-c3ccccc3)cc(-c3nc(-c4ccc5c(c4)oc4ccccc45)nc(-c4ccc5c(c4)oc4ccccc45)n3)cc2-c2ccccc2)cc1 ; c1ccc(-c2ccc3c(c2)c2cc(-c4ccccc4)cc(-c4ccccc4)c2n3-c2c(-c3ccccc3)cc(-c3nc(-c4ccc5c(c4)oc4ccccc45)nc(-c4ccc5c(c4)oc4ccccc45)n3)cc2-c2ccccc2)cc1]

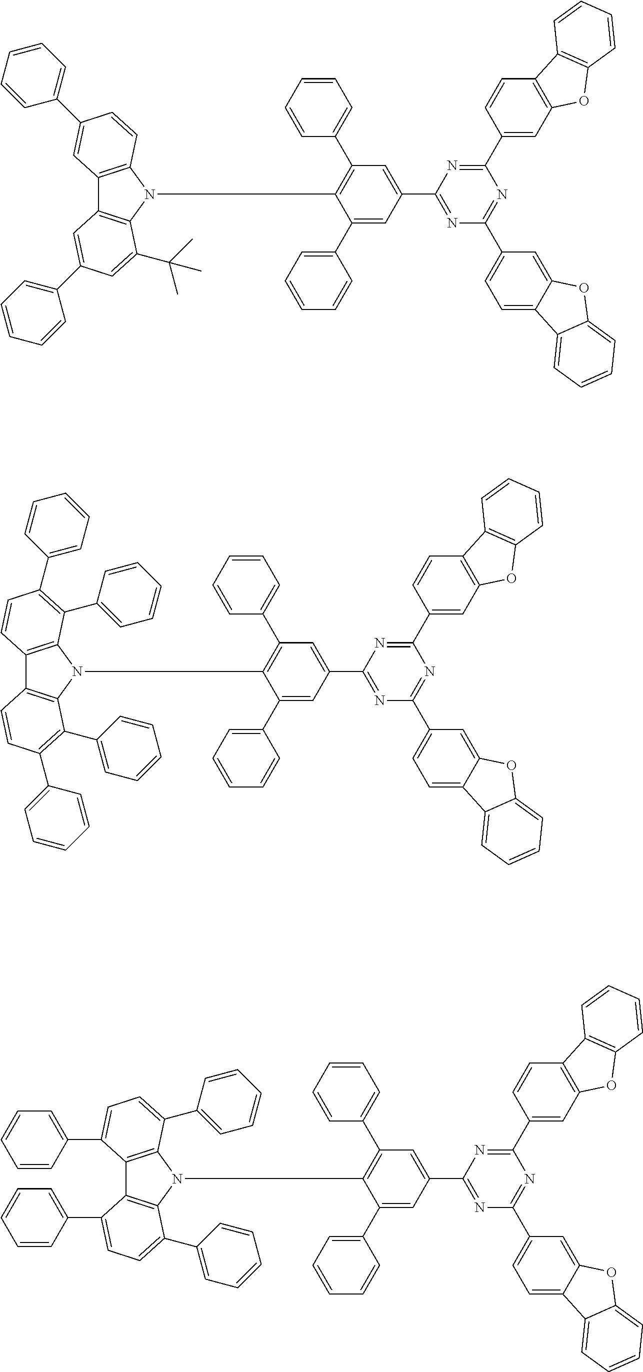 [SMILES: CC(C)(C)c1cc(-c2ccccc2)cc2c3cc(-c4ccccc4)ccc3n(-c3c(-c4ccccc4)cc(-c4nc(-c5ccc6c(c5)oc5ccccc56)nc(-c5ccc6c(c5)oc5ccccc56)n4)cc3-c3ccccc3)c12 ; c1ccc(-c2cc(-c3nc(-c4ccc5c(c4)oc4ccccc45)nc(-c4ccc5c(c4)oc4ccccc45)n3)cc(-c3ccccc3)c2-n2c3c(-c4ccccc4)c(-c4ccccc4)ccc3c3ccc(-c4ccccc4)c(-c4ccccc4)c32)cc1 ; c1ccc(-c2cc(-c3nc(-c4ccc5c(c4)oc4ccccc45)nc(-c4ccc5c(c4)oc4ccccc45)n3)cc(-c3ccccc3)c2-n2c3c(-c4ccccc4)ccc(-c4ccccc4)c3c3c(-c4ccccc4)ccc(-c4ccccc4)c32)cc1]

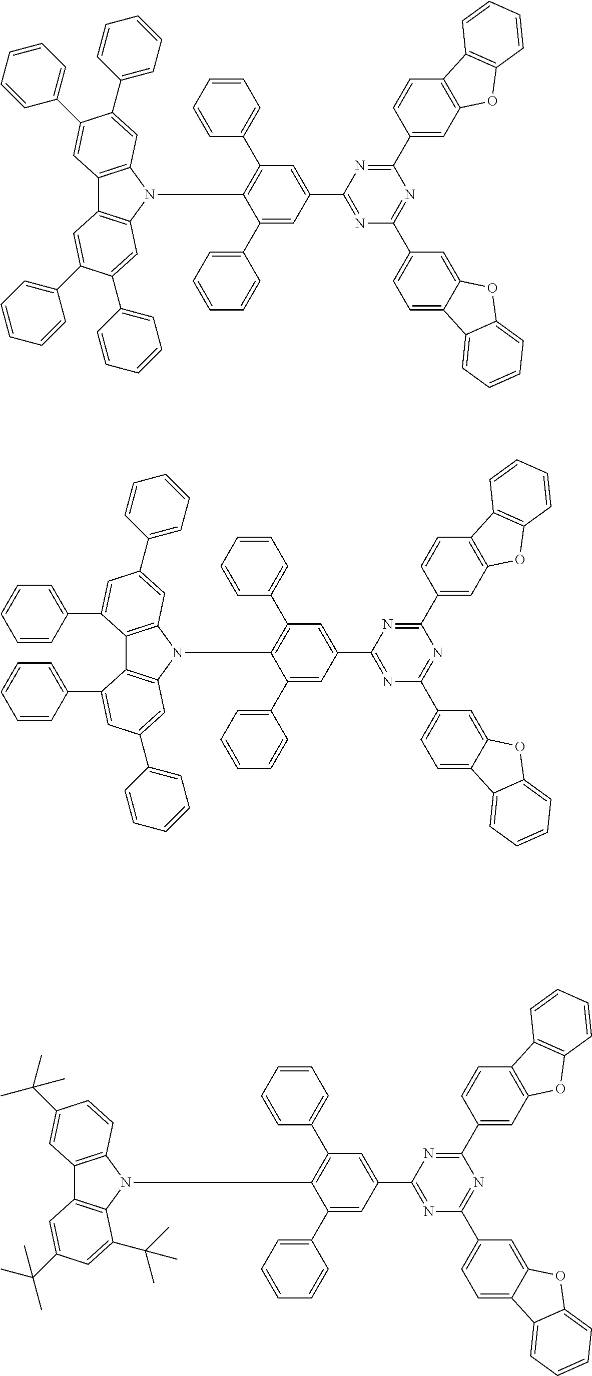 [SMILES: c1ccc(-c2cc3c4cc(-c5ccccc5)c(-c5ccccc5)cc4n(-c4c(-c5ccccc5)cc(-c5nc(-c6ccc7c(c6)oc6ccccc67)nc(-c6ccc7c(c6)oc6ccccc67)n5)cc4-c4ccccc4)c3cc2-c2ccccc2)cc1 ; c1ccc(-c2cc(-c3ccccc3)c3c4c(-c5ccccc5)cc(-c5ccccc5)cc4n(-c4c(-c5ccccc5)cc(-c5nc(-c6ccc7c(c6)oc6ccccc67)nc(-c6ccc7c(c6)oc6ccccc67)n5)cc4-c4ccccc4)c3c2)cc1 ; CC(C)(C)c1ccc2c(c1)c1cc(C(C)(C)C)cc(C(C)(C)C)c1n2-c1c(-c2ccccc2)cc(-c2nc(-c3ccc4c(c3)oc3ccccc34)nc(-c3ccc4c(c3)oc3ccccc34)n2)cc1-c1ccccc1]

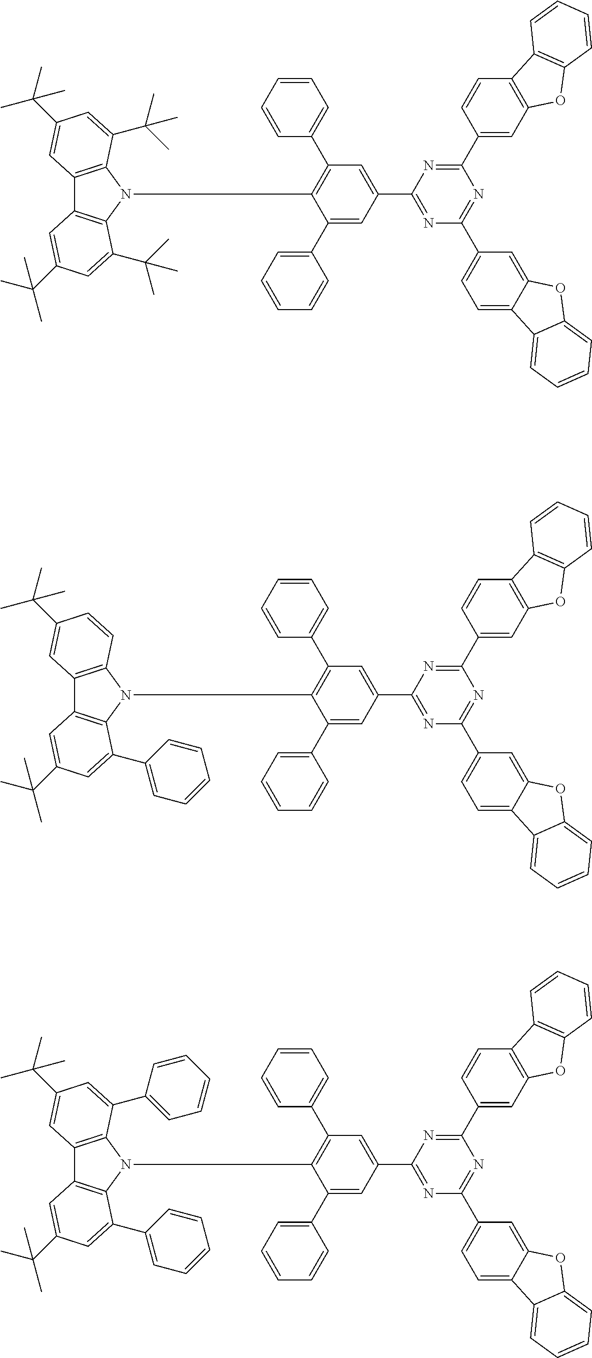 [SMILES: CC(C)(C)c1cc(C(C)(C)C)c2c(c1)c1cc(C(C)(C)C)cc(C(C)(C)C)c1n2-c1c(-c2ccccc2)cc(-c2nc(-c3ccc4c(c3)oc3ccccc34)nc(-c3ccc4c(c3)oc3ccccc34)n2)cc1-c1ccccc1 ; CC(C)(C)c1ccc2c(c1)c1cc(C(C)(C)C)cc(-c3ccccc3)c1n2-c1c(-c2ccccc2)cc(-c2nc(-c3ccc4c(c3)oc3ccccc34)nc(-c3ccc4c(c3)oc3ccccc34)n2)cc1-c1ccccc1 ; CC(C)(C)c1cc(-c2ccccc2)c2c(c1)c1cc(C(C)(C)C)cc(-c3ccccc3)c1n2-c1c(-c2ccccc2)cc(-c2nc(-c3ccc4c(c3)oc3ccccc34)nc(-c3ccc4c(c3)oc3ccccc34)n2)cc1-c1ccccc1]

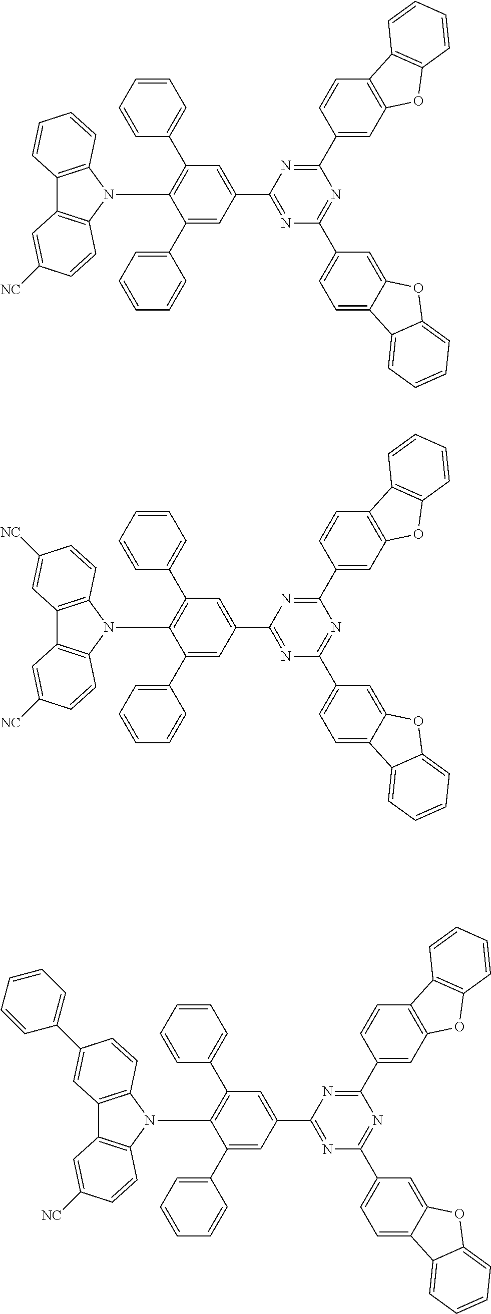 [SMILES: N#Cc1ccc2c(c1)c1ccccc1n2-c1c(-c2ccccc2)cc(-c2nc(-c3ccc4c(c3)oc3ccccc34)nc(-c3ccc4c(c3)oc3ccccc34)n2)cc1-c1ccccc1 ; N#Cc1ccc2c(c1)c1cc(C#N)ccc1n2-c1c(-c2ccccc2)cc(-c2nc(-c3ccc4c(c3)oc3ccccc34)nc(-c3ccc4c(c3)oc3ccccc34)n2)cc1-c1ccccc1 ; N#Cc1ccc2c(c1)c1cc(-c3ccccc3)ccc1n2-c1c(-c2ccccc2)cc(-c2nc(-c3ccc4c(c3)oc3ccccc34)nc(-c3ccc4c(c3)oc3ccccc34)n2)cc1-c1ccccc1]

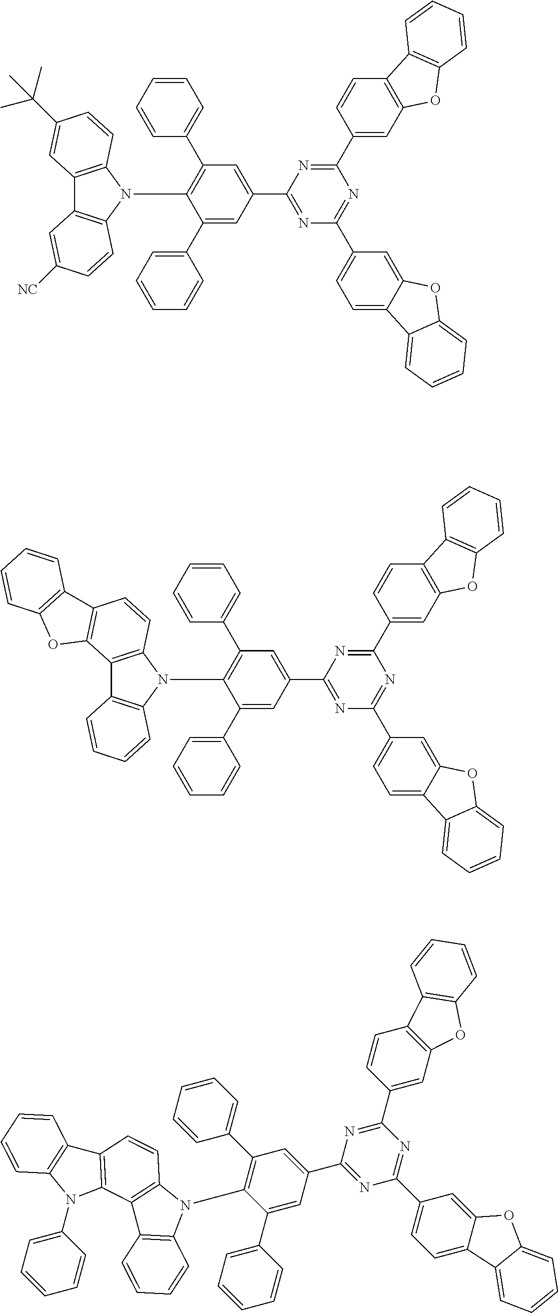 [SMILES: CC(C)(C)c1ccc2c(c1)c1cc(C#N)ccc1n2-c1c(-c2ccccc2)cc(-c2nc(-c3ccc4c(c3)oc3ccccc34)nc(-c3ccc4c(c3)oc3ccccc34)n2)cc1-c1ccccc1 ; c1ccc(-c2cc(-c3nc(-c4ccc5c(c4)oc4ccccc45)nc(-c4ccc5c(c4)oc4ccccc45)n3)cc(-c3ccccc3)c2-n2c3ccccc3c3c4oc5ccccc5c4ccc32)cc1 ; c1ccc(-c2cc(-c3nc(-c4ccc5c(c4)oc4ccccc45)nc(-c4ccc5c(c4)oc4ccccc45)n3)cc(-c3ccccc3)c2-n2c3ccccc3c3c2ccc2c4ccccc4n(-c4ccccc4)c23)cc1]

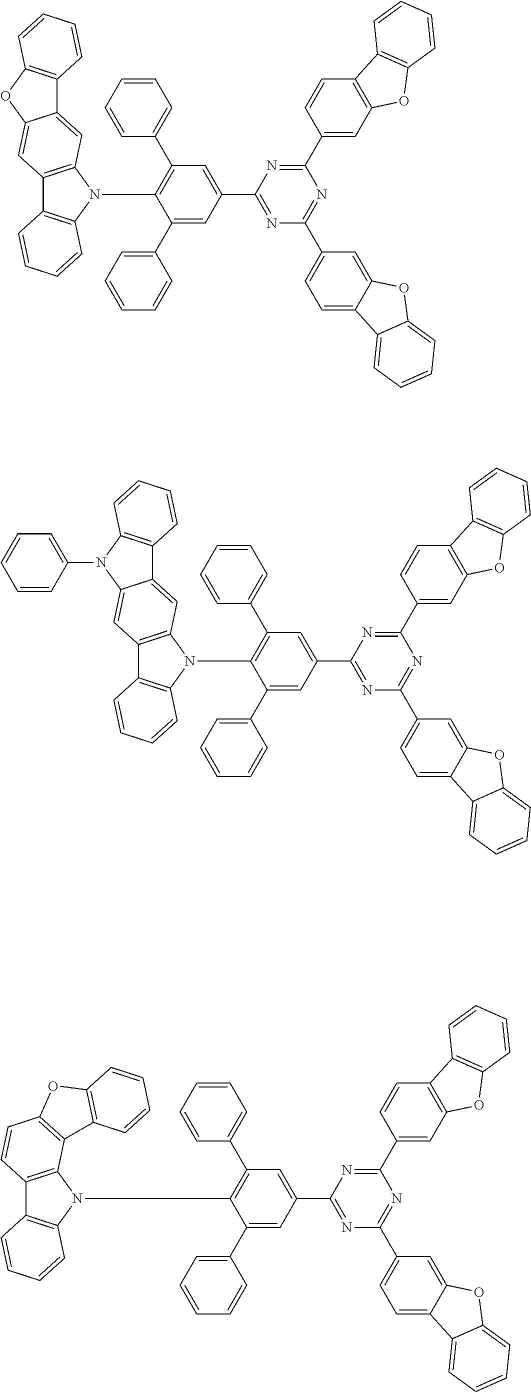 [SMILES: c1ccc(-c2cc(-c3nc(-c4ccc5c(c4)oc4ccccc45)nc(-c4ccc5c(c4)oc4ccccc45)n3)cc(-c3ccccc3)c2-n2c3ccccc3c3cc4oc5ccccc5c4cc32)cc1 ; c1ccc(-c2cc(-c3nc(-c4ccc5c(c4)oc4ccccc45)nc(-c4ccc5c(c4)oc4ccccc45)n3)cc(-c3ccccc3)c2-n2c3ccccc3c3cc4c(cc32)c2ccccc2n4-c2ccccc2)cc1 ; c1ccc(-c2cc(-c3nc(-c4ccc5c(c4)oc4ccccc45)nc(-c4ccc5c(c4)oc4ccccc45)n3)cc(-c3ccccc3)c2-n2c3ccccc3c3ccc4oc5ccccc5c4c32)cc1]

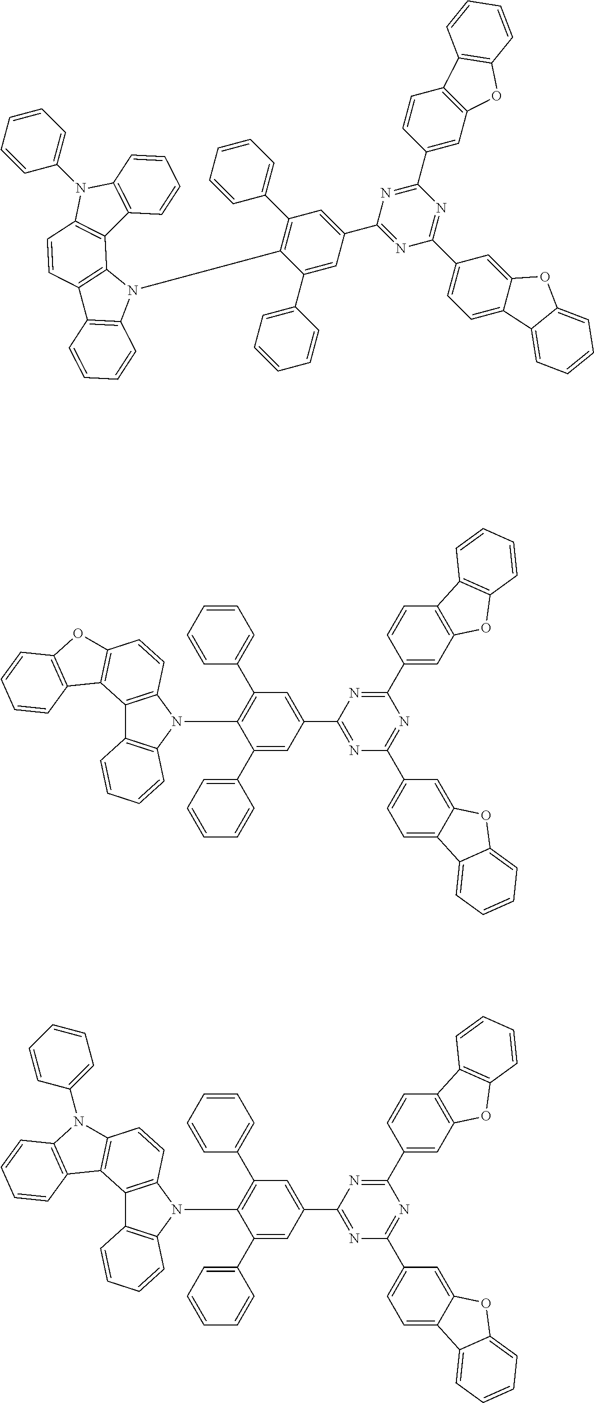 [SMILES: c1ccc(-c2cc(-c3nc(-c4ccc5c(c4)oc4ccccc45)nc(-c4ccc5c(c4)oc4ccccc45)n3)cc(-c3ccccc3)c2-n2c3ccccc3c3ccc4c(c5ccccc5n4-c4ccccc4)c32)cc1 ; c1ccc(-c2cc(-c3nc(-c4ccc5c(c4)oc4ccccc45)nc(-c4ccc5c(c4)oc4ccccc45)n3)cc(-c3ccccc3)c2-n2c3ccccc3c3c4c(ccc32)oc2ccccc24)cc1 ; c1ccc(-c2cc(-c3nc(-c4ccc5c(c4)oc4ccccc45)nc(-c4ccc5c(c4)oc4ccccc45)n3)cc(-c3ccccc3)c2-n2c3ccccc3c3c4c5ccccc5n(-c5ccccc5)c4ccc32)cc1]

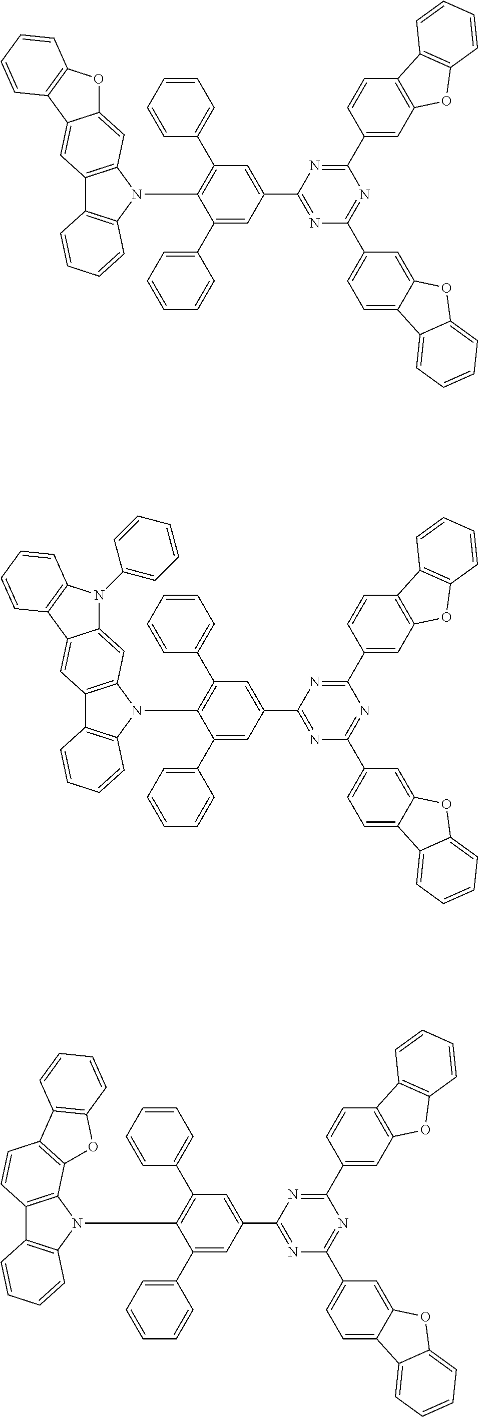 [SMILES: c1ccc(-c2cc(-c3nc(-c4ccc5c(c4)oc4ccccc45)nc(-c4ccc5c(c4)oc4ccccc45)n3)cc(-c3ccccc3)c2-n2c3ccccc3c3cc4c(cc32)oc2ccccc24)cc1 ; c1ccc(-c2cc(-c3nc(-c4ccc5c(c4)oc4ccccc45)nc(-c4ccc5c(c4)oc4ccccc45)n3)cc(-c3ccccc3)c2-n2c3ccccc3c3cc4c5ccccc5n(-c5ccccc5)c4cc32)cc1 ; c1ccc(-c2cc(-c3nc(-c4ccc5c(c4)oc4ccccc45)nc(-c4ccc5c(c4)oc4ccccc45)n3)cc(-c3ccccc3)c2-n2c3ccccc3c3ccc4c5ccccc5oc4c32)cc1]

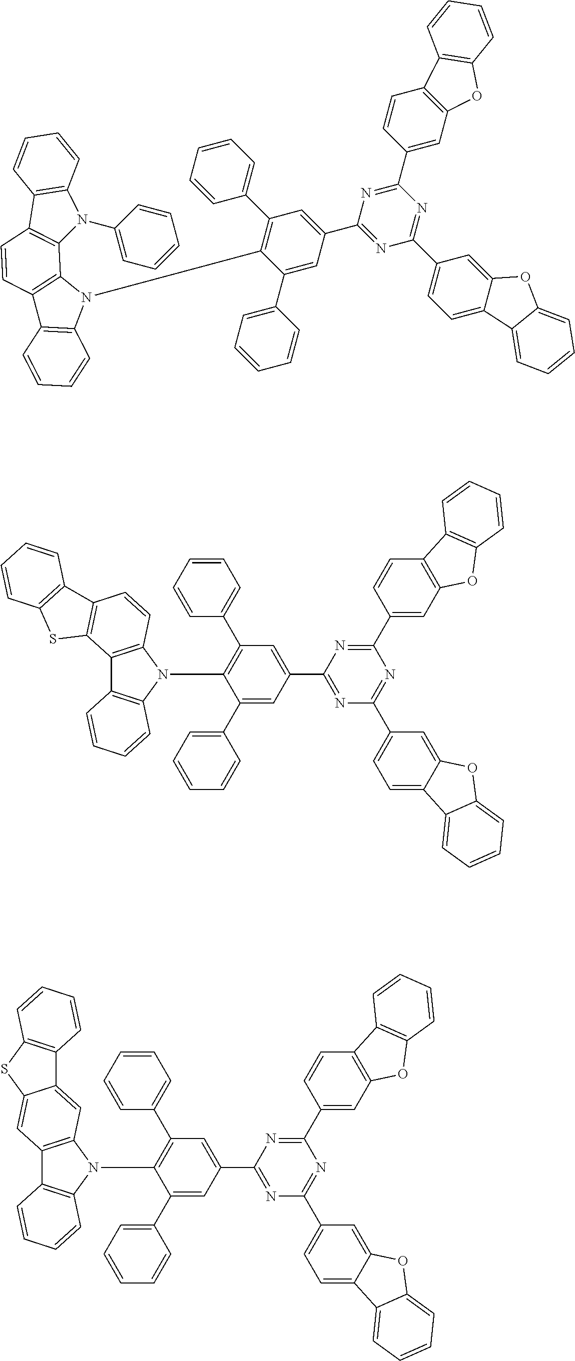 [SMILES: c1ccc(-c2cc(-c3nc(-c4ccc5c(c4)oc4ccccc45)nc(-c4ccc5c(c4)oc4ccccc45)n3)cc(-c3ccccc3)c2-n2c3ccccc3c3ccc4c5ccccc5n(-c5ccccc5)c4c32)cc1 ; c1ccc(-c2cc(-c3nc(-c4ccc5c(c4)oc4ccccc45)nc(-c4ccc5c(c4)oc4ccccc45)n3)cc(-c3ccccc3)c2-n2c3ccccc3c3c4sc5ccccc5c4ccc32)cc1 ; c1ccc(-c2cc(-c3nc(-c4ccc5c(c4)oc4ccccc45)nc(-c4ccc5c(c4)oc4ccccc45)n3)cc(-c3ccccc3)c2-n2c3ccccc3c3cc4sc5ccccc5c4cc32)cc1]

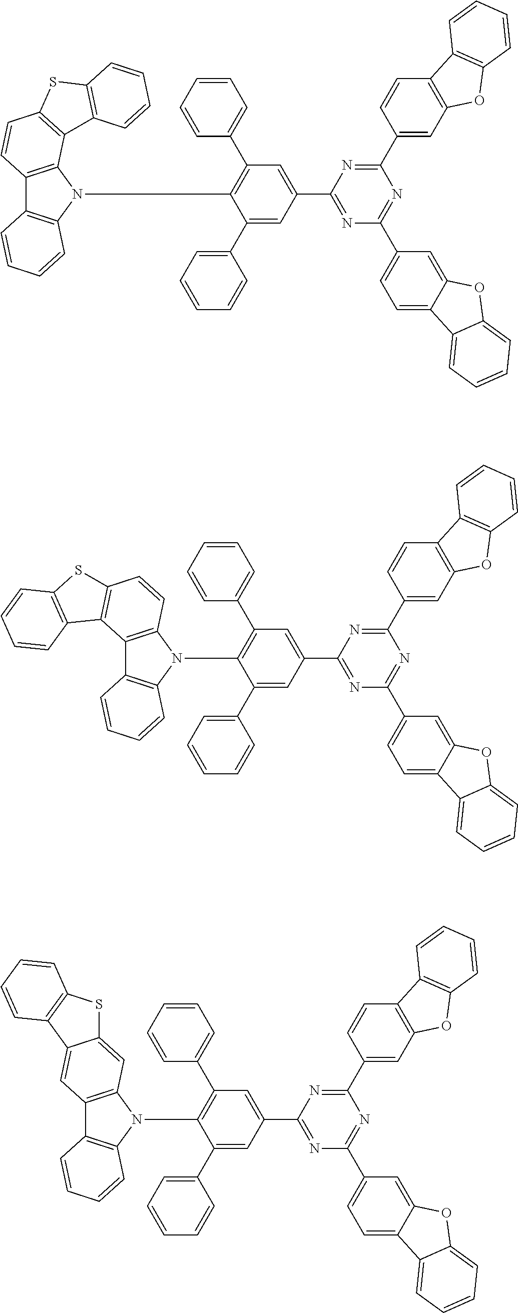 [SMILES: c1ccc(-c2cc(-c3nc(-c4ccc5c(c4)oc4ccccc45)nc(-c4ccc5c(c4)oc4ccccc45)n3)cc(-c3ccccc3)c2-n2c3ccccc3c3ccc4sc5ccccc5c4c32)cc1 ; c1ccc(-c2cc(-c3nc(-c4ccc5c(c4)oc4ccccc45)nc(-c4ccc5c(c4)oc4ccccc45)n3)cc(-c3ccccc3)c2-n2c3ccccc3c3c4c(ccc32)sc2ccccc24)cc1 ; c1ccc(-c2cc(-c3nc(-c4ccc5c(c4)oc4ccccc45)nc(-c4ccc5c(c4)oc4ccccc45)n3)cc(-c3ccccc3)c2-n2c3ccccc3c3cc4c(cc32)sc2ccccc24)cc1]

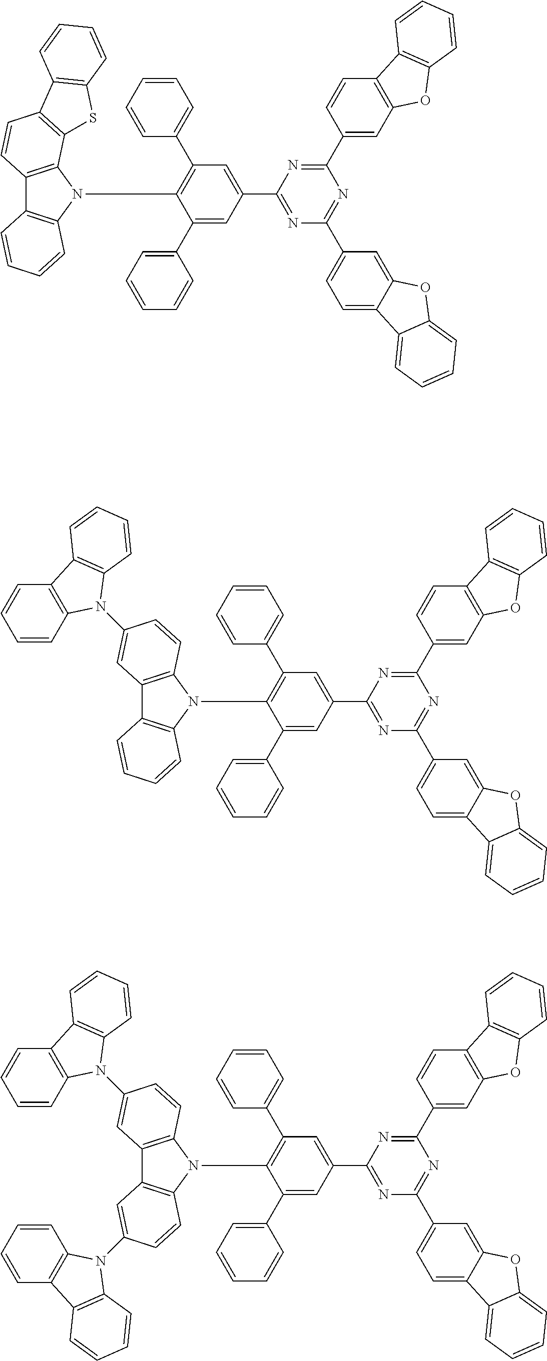 [SMILES: c1ccc(-c2cc(-c3nc(-c4ccc5c(c4)oc4ccccc45)nc(-c4ccc5c(c4)oc4ccccc45)n3)cc(-c3ccccc3)c2-n2c3ccccc3c3ccc4c5ccccc5sc4c32)cc1 ; c1ccc(-c2cc(-c3nc(-c4ccc5c(c4)oc4ccccc45)nc(-c4ccc5c(c4)oc4ccccc45)n3)cc(-c3ccccc3)c2-n2c3ccccc3c3cc(-n4c5ccccc5c5ccccc54)ccc32)cc1 ; c1ccc(-c2cc(-c3nc(-c4ccc5c(c4)oc4ccccc45)nc(-c4ccc5c(c4)oc4ccccc45)n3)cc(-c3ccccc3)c2-n2c3ccc(-n4c5ccccc5c5ccccc54)cc3c3cc(-n4c5ccccc5c5ccccc54)ccc32)cc1]

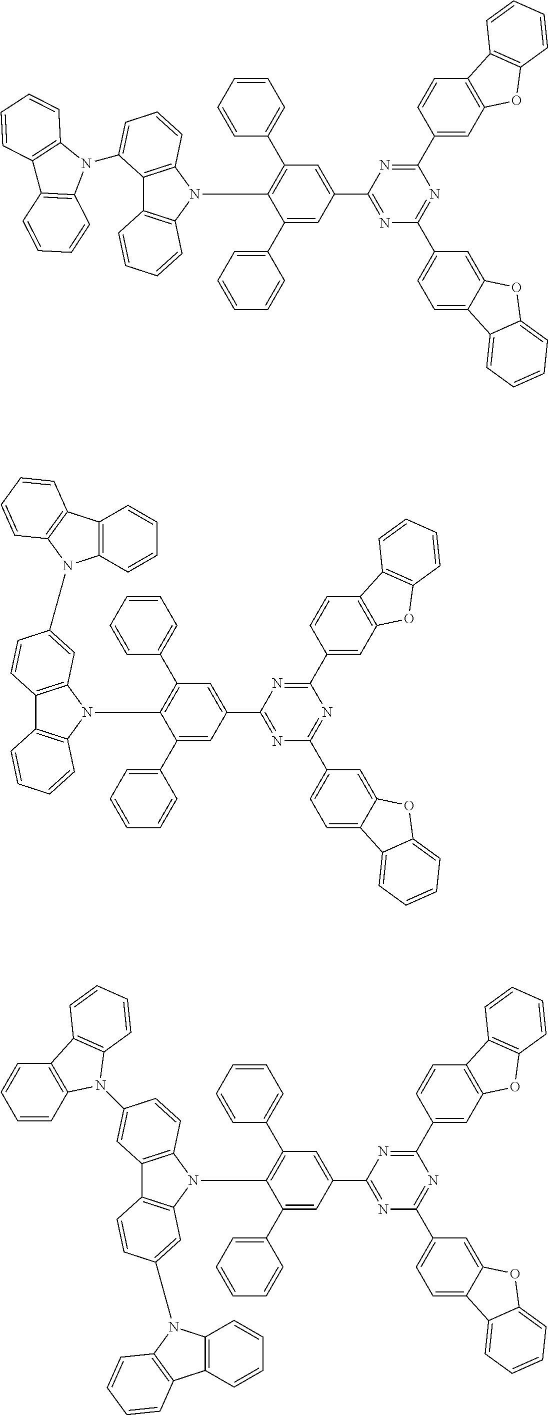 [SMILES: c1ccc(-c2cc(-c3nc(-c4ccc5c(c4)oc4ccccc45)nc(-c4ccc5c(c4)oc4ccccc45)n3)cc(-c3ccccc3)c2-n2c3ccccc3c3c(-n4c5ccccc5c5ccccc54)cccc32)cc1 ; c1ccc(-c2cc(-c3nc(-c4ccc5c(c4)oc4ccccc45)nc(-c4ccc5c(c4)oc4ccccc45)n3)cc(-c3ccccc3)c2-n2c3ccccc3c3ccc(-n4c5ccccc5c5ccccc54)cc32)cc1 ; c1ccc(-c2cc(-c3nc(-c4ccc5c(c4)oc4ccccc45)nc(-c4ccc5c(c4)oc4ccccc45)n3)cc(-c3ccccc3)c2-n2c3ccc(-n4c5ccccc5c5ccccc54)cc3c3ccc(-n4c5ccccc5c5ccccc54)cc32)cc1]

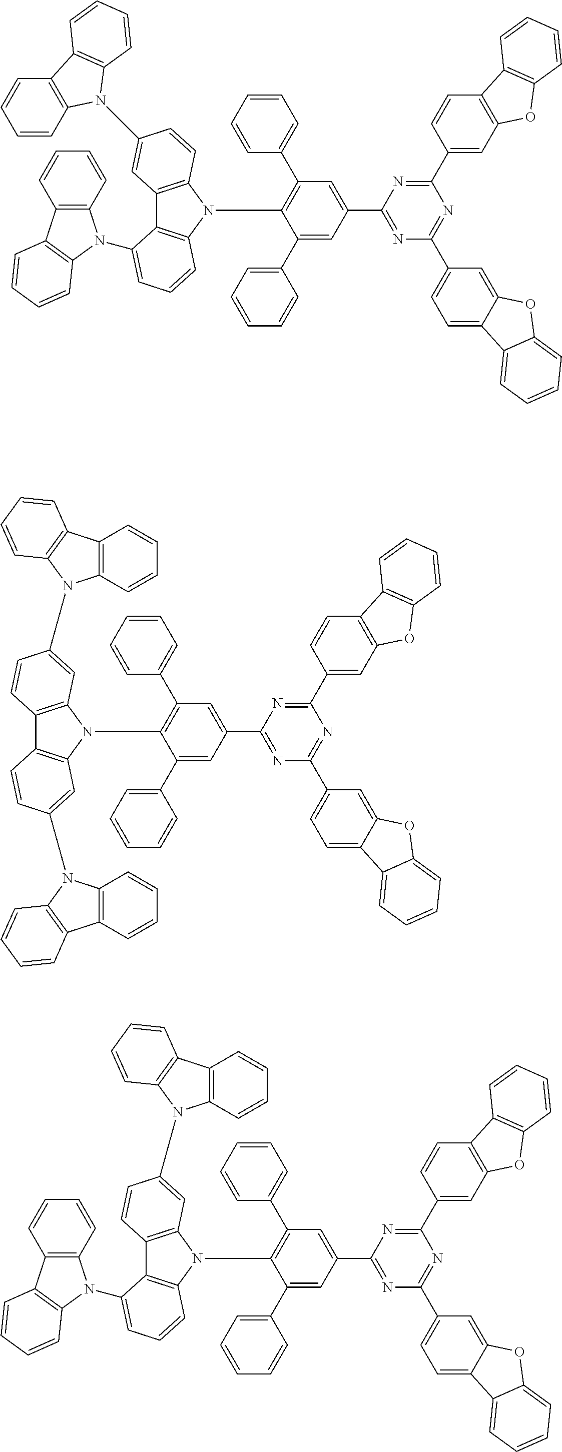 [SMILES: c1ccc(-c2cc(-c3nc(-c4ccc5c(c4)oc4ccccc45)nc(-c4ccc5c(c4)oc4ccccc45)n3)cc(-c3ccccc3)c2-n2c3ccc(-n4c5ccccc5c5ccccc54)cc3c3c(-n4c5ccccc5c5ccccc54)cccc32)cc1 ; c1ccc(-c2cc(-c3nc(-c4ccc5c(c4)oc4ccccc45)nc(-c4ccc5c(c4)oc4ccccc45)n3)cc(-c3ccccc3)c2-n2c3cc(-n4c5ccccc5c5ccccc54)ccc3c3ccc(-n4c5ccccc5c5ccccc54)cc32)cc1 ; c1ccc(-c2cc(-c3nc(-c4ccc5c(c4)oc4ccccc45)nc(-c4ccc5c(c4)oc4ccccc45)n3)cc(-c3ccccc3)c2-n2c3cc(-n4c5ccccc5c5ccccc54)ccc3c3c(-n4c5ccccc5c5ccccc54)cccc32)cc1]

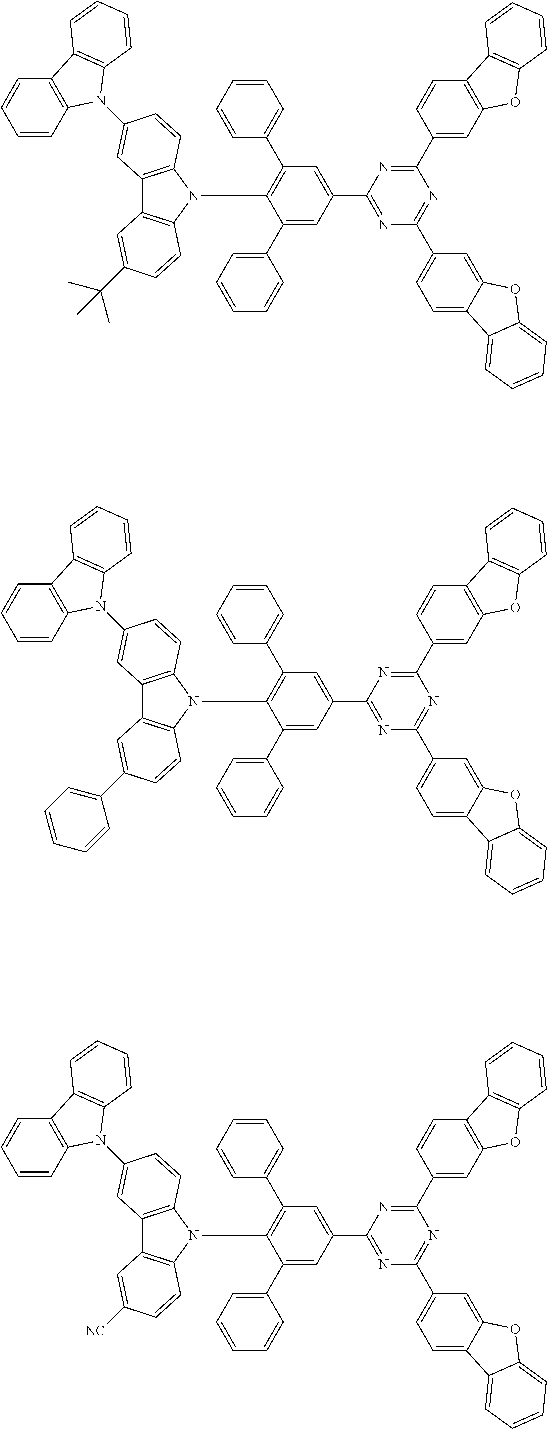 [SMILES: CC(C)(C)c1ccc2c(c1)c1cc(-n3c4ccccc4c4ccccc43)ccc1n2-c1c(-c2ccccc2)cc(-c2nc(-c3ccc4c(c3)oc3ccccc34)nc(-c3ccc4c(c3)oc3ccccc34)n2)cc1-c1ccccc1 ; c1ccc(-c2ccc3c(c2)c2cc(-n4c5ccccc5c5ccccc54)ccc2n3-c2c(-c3ccccc3)cc(-c3nc(-c4ccc5c(c4)oc4ccccc45)nc(-c4ccc5c(c4)oc4ccccc45)n3)cc2-c2ccccc2)cc1 ; N#Cc1ccc2c(c1)c1cc(-n3c4ccccc4c4ccccc43)ccc1n2-c1c(-c2ccccc2)cc(-c2nc(-c3ccc4c(c3)oc3ccccc34)nc(-c3ccc4c(c3)oc3ccccc34)n2)cc1-c1ccccc1]

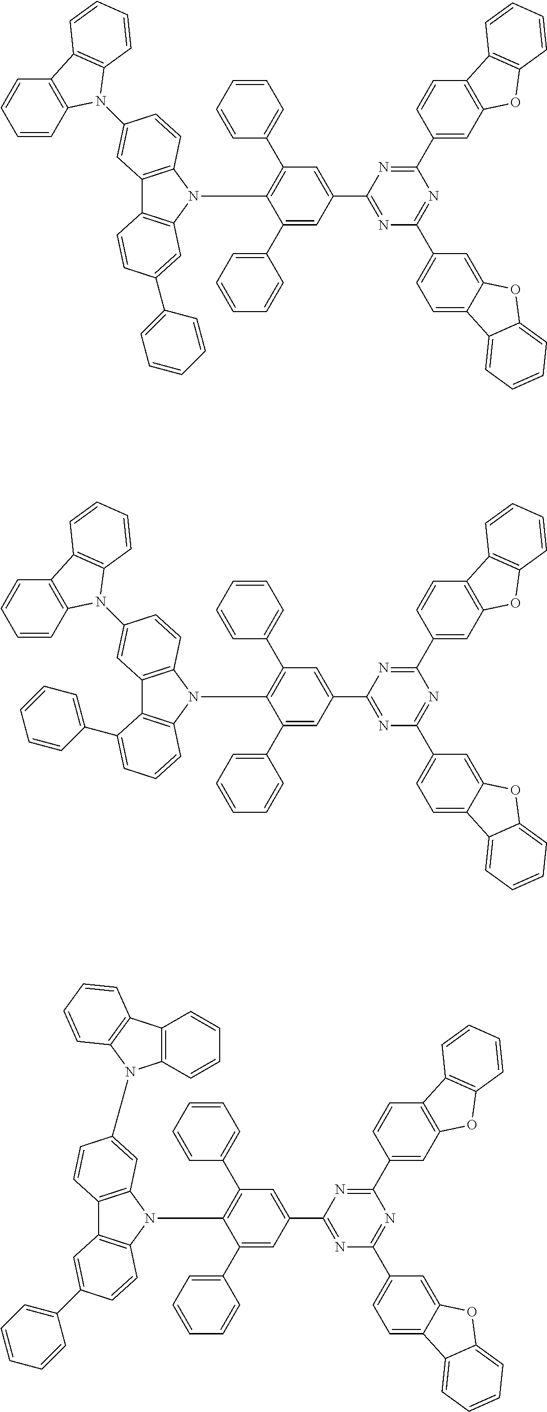 [SMILES: c1ccc(-c2ccc3c4cc(-n5c6ccccc6c6ccccc65)ccc4n(-c4c(-c5ccccc5)cc(-c5nc(-c6ccc7c(c6)oc6ccccc67)nc(-c6ccc7c(c6)oc6ccccc67)n5)cc4-c4ccccc4)c3c2)cc1 ; c1ccc(-c2cc(-c3nc(-c4ccc5c(c4)oc4ccccc45)nc(-c4ccc5c(c4)oc4ccccc45)n3)cc(-c3ccccc3)c2-n2c3ccc(-n4c5ccccc5c5ccccc54)cc3c3c(-c4ccccc4)cccc32)cc1 ; c1ccc(-c2ccc3c(c2)c2ccc(-n4c5ccccc5c5ccccc54)cc2n3-c2c(-c3ccccc3)cc(-c3nc(-c4ccc5c(c4)oc4ccccc45)nc(-c4ccc5c(c4)oc4ccccc45)n3)cc2-c2ccccc2)cc1]

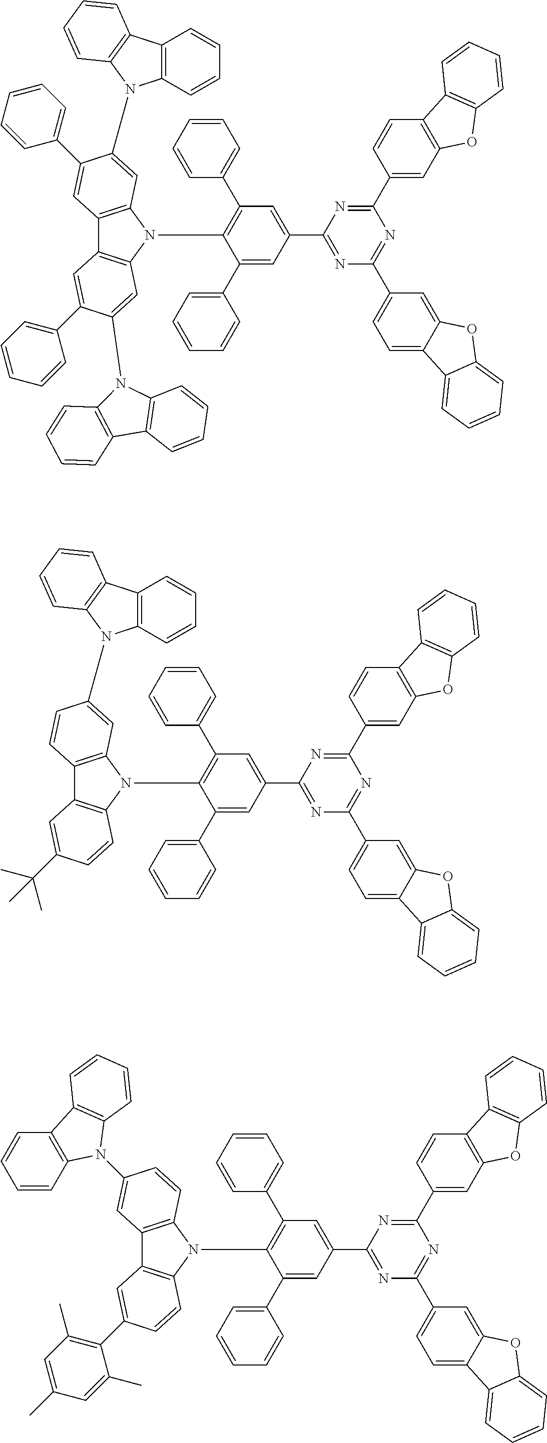 [SMILES: c1ccc(-c2cc3c4cc(-c5ccccc5)c(-n5c6ccccc6c6ccccc65)cc4n(-c4c(-c5ccccc5)cc(-c5nc(-c6ccc7c(c6)oc6ccccc67)nc(-c6ccc7c(c6)oc6ccccc67)n5)cc4-c4ccccc4)c3cc2-n2c3ccccc3c3ccccc32)cc1 ; CC(C)(C)c1ccc2c(c1)c1ccc(-n3c4ccccc4c4ccccc43)cc1n2-c1c(-c2ccccc2)cc(-c2nc(-c3ccc4c(c3)oc3ccccc34)nc(-c3ccc4c(c3)oc3ccccc34)n2)cc1-c1ccccc1 ; Cc1cc(C)c(-c2ccc3c(c2)c2cc(-n4c5ccccc5c5ccccc54)ccc2n3-c2c(-c3ccccc3)cc(-c3nc(-c4ccc5c(c4)oc4ccccc45)nc(-c4ccc5c(c4)oc4ccccc45)n3)cc2-c2ccccc2)c(C)c1]

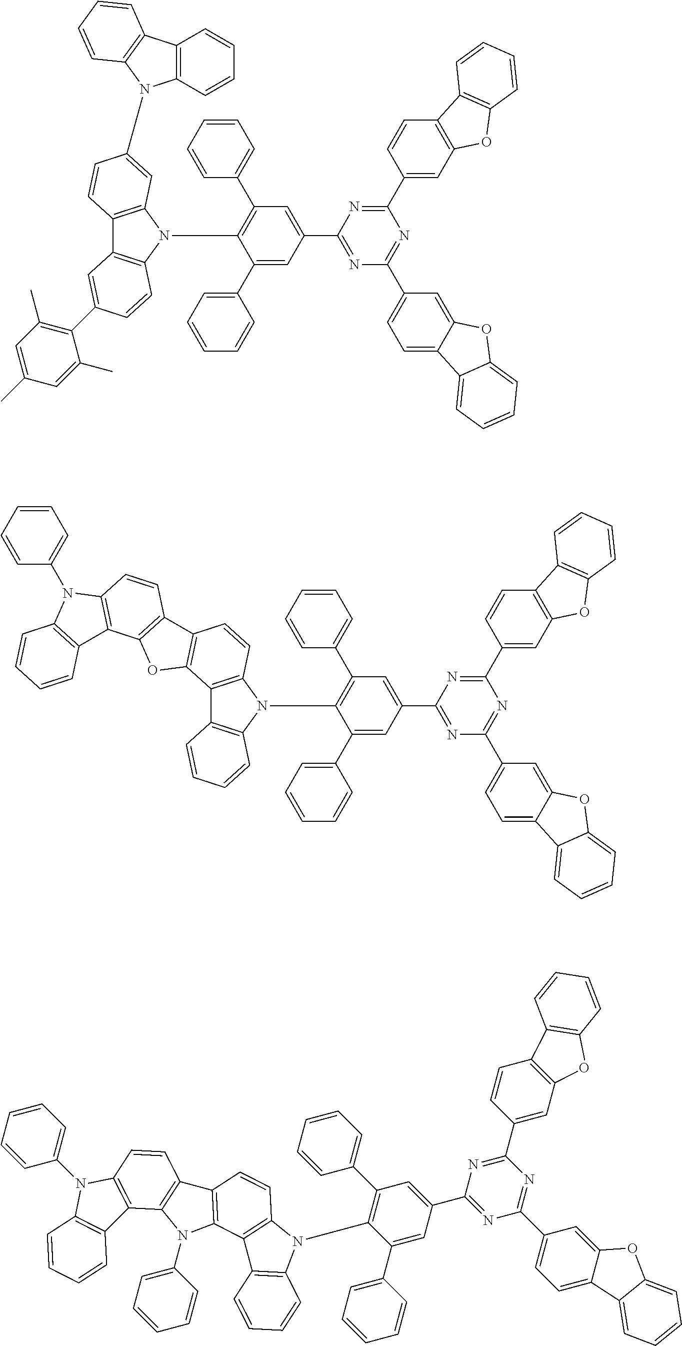 [SMILES: Cc1cc(C)c(-c2ccc3c(c2)c2ccc(-n4c5ccccc5c5ccccc54)cc2n3-c2c(-c3ccccc3)cc(-c3nc(-c4ccc5c(c4)oc4ccccc45)nc(-c4ccc5c(c4)oc4ccccc45)n3)cc2-c2ccccc2)c(C)c1 ; c1ccc(-c2cc(-c3nc(-c4ccc5c(c4)oc4ccccc45)nc(-c4ccc5c(c4)oc4ccccc45)n3)cc(-c3ccccc3)c2-n2c3ccccc3c3c4oc5c(ccc6c5c5ccccc5n6-c5ccccc5)c4ccc32)cc1 ; c1ccc(-c2cc(-c3nc(-c4ccc5c(c4)oc4ccccc45)nc(-c4ccc5c(c4)oc4ccccc45)n3)cc(-c3ccccc3)c2-n2c3ccccc3c3c2ccc2c4ccc5c(c6ccccc6n5-c5ccccc5)c4n(-c4ccccc4)c23)cc1]

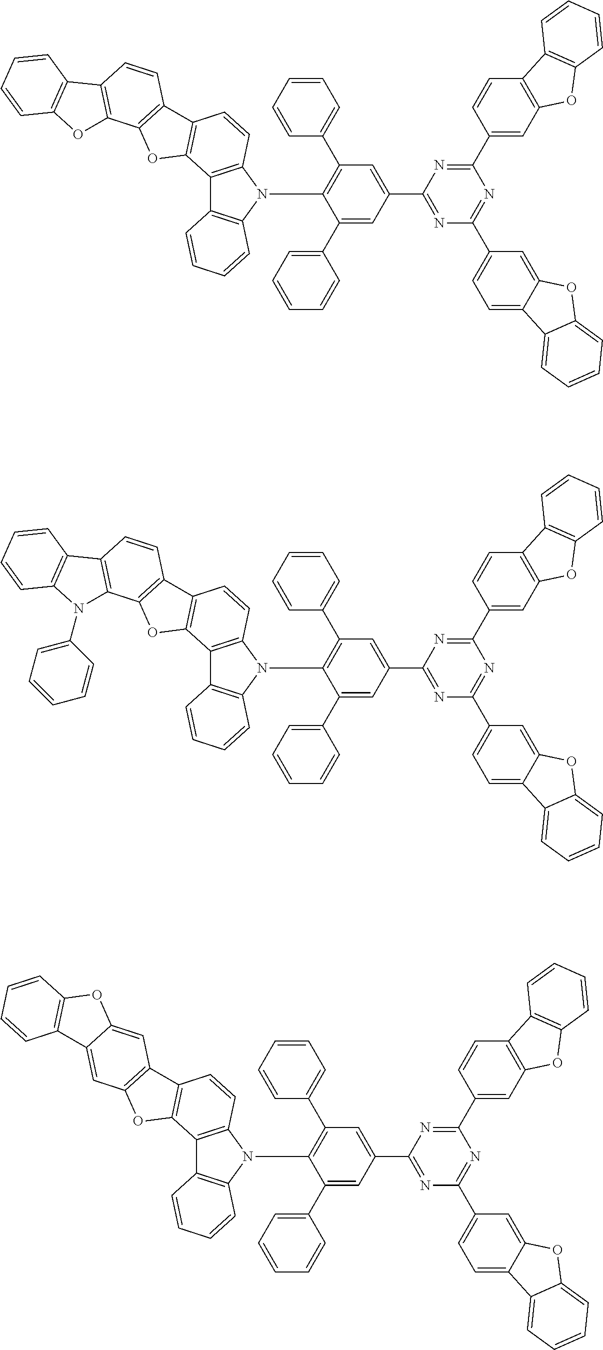 [SMILES: c1ccc(-c2cc(-c3nc(-c4ccc5c(c4)oc4ccccc45)nc(-c4ccc5c(c4)oc4ccccc45)n3)cc(-c3ccccc3)c2-n2c3ccccc3c3c4oc5c(ccc6c7ccccc7oc65)c4ccc32)cc1 ; c1ccc(-c2cc(-c3nc(-c4ccc5c(c4)oc4ccccc45)nc(-c4ccc5c(c4)oc4ccccc45)n3)cc(-c3ccccc3)c2-n2c3ccccc3c3c4oc5c(ccc6c7ccccc7n(-c7ccccc7)c65)c4ccc32)cc1 ; c1ccc(-c2cc(-c3nc(-c4ccc5c(c4)oc4ccccc45)nc(-c4ccc5c(c4)oc4ccccc45)n3)cc(-c3ccccc3)c2-n2c3ccccc3c3c4oc5cc6c(cc5c4ccc32)oc2ccccc26)cc1]

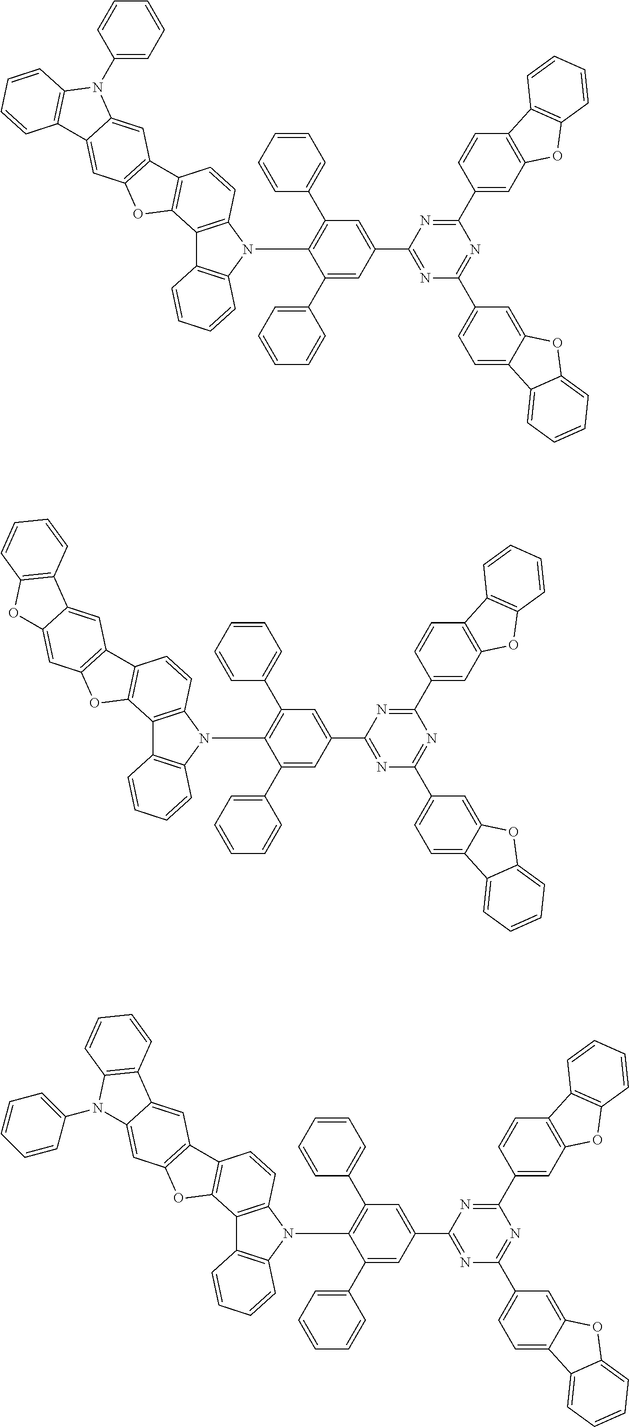 [SMILES: c1ccc(-c2cc(-c3nc(-c4ccc5c(c4)oc4ccccc45)nc(-c4ccc5c(c4)oc4ccccc45)n3)cc(-c3ccccc3)c2-n2c3ccccc3c3c4oc5cc6c7ccccc7n(-c7ccccc7)c6cc5c4ccc32)cc1 ; c1ccc(-c2cc(-c3nc(-c4ccc5c(c4)oc4ccccc45)nc(-c4ccc5c(c4)oc4ccccc45)n3)cc(-c3ccccc3)c2-n2c3ccccc3c3c4oc5cc6oc7ccccc7c6cc5c4ccc32)cc1 ; c1ccc(-c2cc(-c3nc(-c4ccc5c(c4)oc4ccccc45)nc(-c4ccc5c(c4)oc4ccccc45)n3)cc(-c3ccccc3)c2-n2c3ccccc3c3c4oc5cc6c(cc5c4ccc32)c2ccccc2n6-c2ccccc2)cc1]

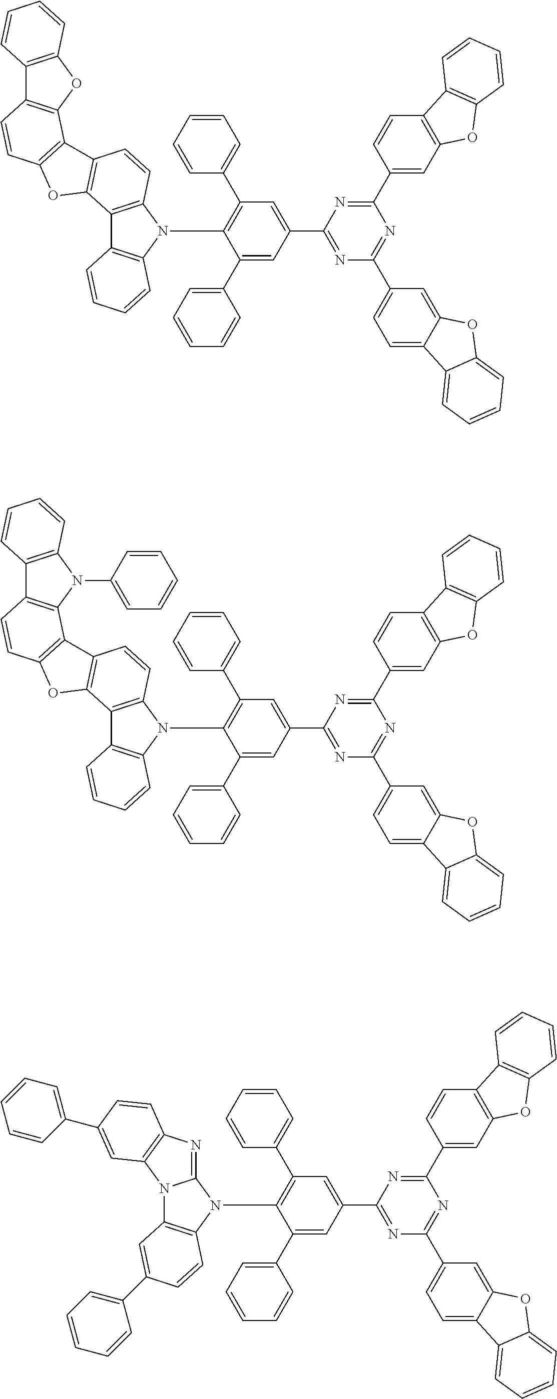 [SMILES: c1ccc(-c2cc(-c3nc(-c4ccc5c(c4)oc4ccccc45)nc(-c4ccc5c(c4)oc4ccccc45)n3)cc(-c3ccccc3)c2-n2c3ccccc3c3c4oc5ccc6c7ccccc7oc6c5c4ccc32)cc1 ; c1ccc(-c2cc(-c3nc(-c4ccc5c(c4)oc4ccccc45)nc(-c4ccc5c(c4)oc4ccccc45)n3)cc(-c3ccccc3)c2-n2c3ccccc3c3c4oc5ccc6c7ccccc7n(-c7ccccc7)c6c5c4ccc32)cc1 ; c1ccc(-c2ccc3nc4n(-c5c(-c6ccccc6)cc(-c6nc(-c7ccc8c(c7)oc7ccccc78)nc(-c7ccc8c(c7)oc7ccccc78)n6)cc5-c5ccccc5)c5ccc(-c6ccccc6)cc5n4c3c2)cc1]

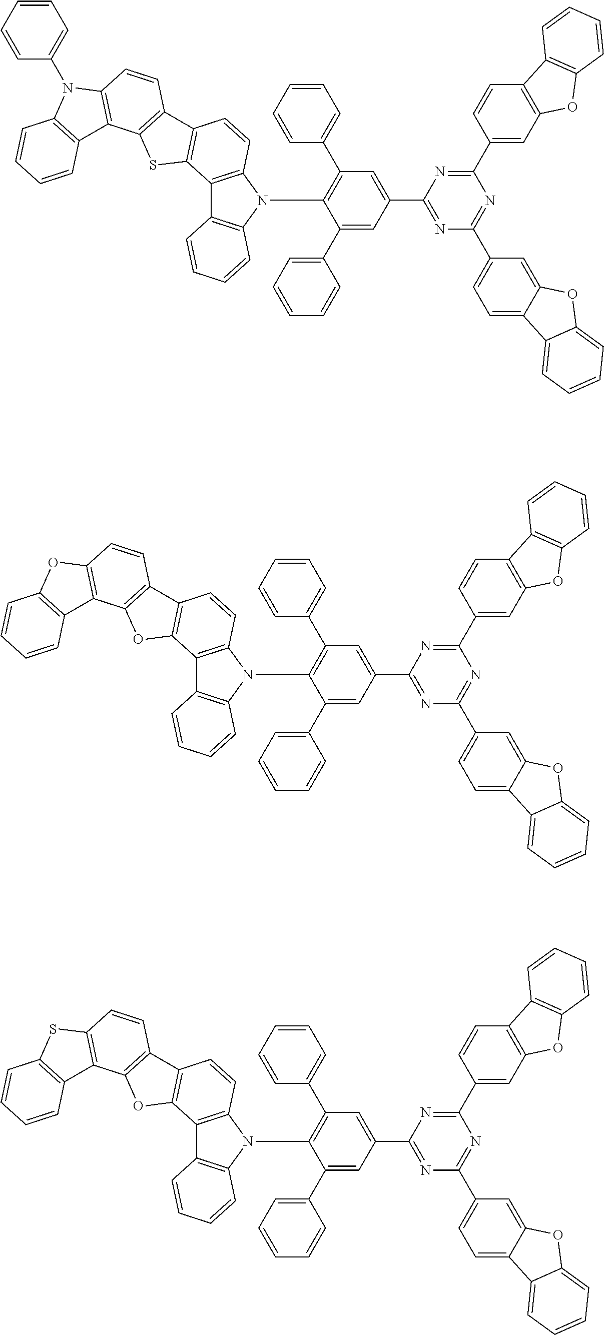 [SMILES: c1ccc(-c2cc(-c3nc(-c4ccc5c(c4)oc4ccccc45)nc(-c4ccc5c(c4)oc4ccccc45)n3)cc(-c3ccccc3)c2-n2c3ccccc3c3c4sc5c(ccc6c5c5ccccc5n6-c5ccccc5)c4ccc32)cc1 ; c1ccc(-c2cc(-c3nc(-c4ccc5c(c4)oc4ccccc45)nc(-c4ccc5c(c4)oc4ccccc45)n3)cc(-c3ccccc3)c2-n2c3ccccc3c3c4oc5c(ccc6oc7ccccc7c65)c4ccc32)cc1 ; c1ccc(-c2cc(-c3nc(-c4ccc5c(c4)oc4ccccc45)nc(-c4ccc5c(c4)oc4ccccc45)n3)cc(-c3ccccc3)c2-n2c3ccccc3c3c4oc5c(ccc6sc7ccccc7c65)c4ccc32)cc1]

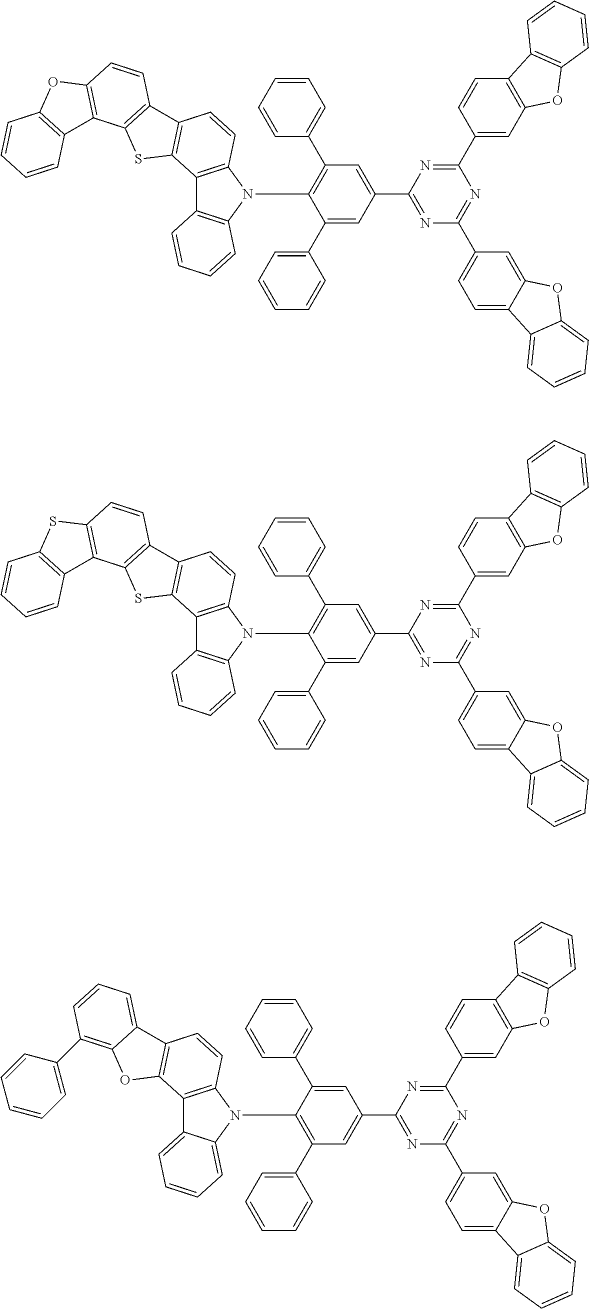 [SMILES: c1ccc(-c2cc(-c3nc(-c4ccc5c(c4)oc4ccccc45)nc(-c4ccc5c(c4)oc4ccccc45)n3)cc(-c3ccccc3)c2-n2c3ccccc3c3c4sc5c(ccc6oc7ccccc7c65)c4ccc32)cc1 ; c1ccc(-c2cc(-c3nc(-c4ccc5c(c4)oc4ccccc45)nc(-c4ccc5c(c4)oc4ccccc45)n3)cc(-c3ccccc3)c2-n2c3ccccc3c3c4sc5c(ccc6sc7ccccc7c65)c4ccc32)cc1 ; c1ccc(-c2cc(-c3nc(-c4ccc5c(c4)oc4ccccc45)nc(-c4ccc5c(c4)oc4ccccc45)n3)cc(-c3ccccc3)c2-n2c3ccccc3c3c4oc5c(-c6ccccc6)cccc5c4ccc32)cc1]

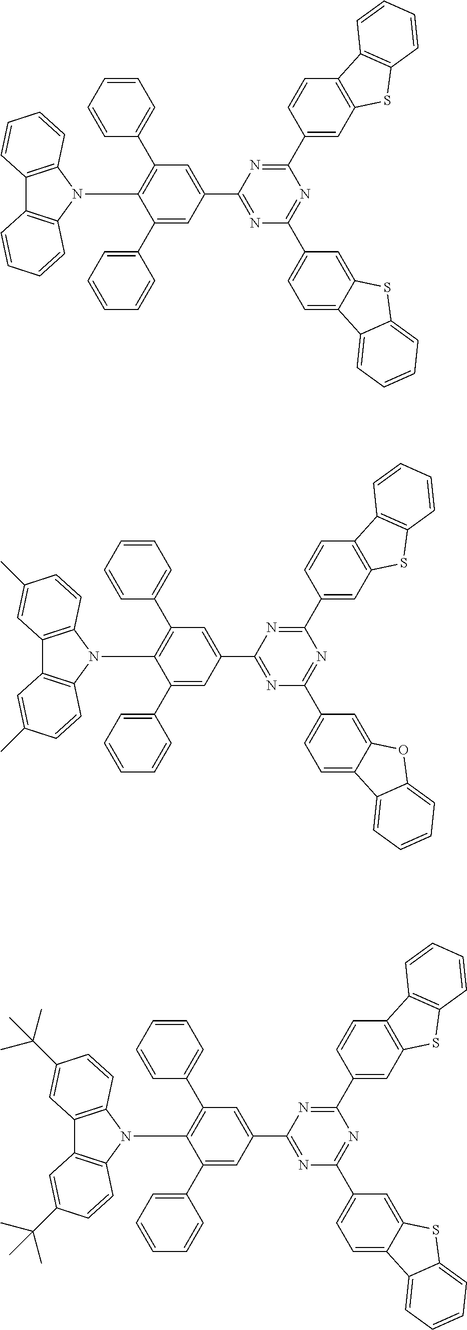 [SMILES: c1ccc(-c2cc(-c3nc(-c4ccc5c(c4)sc4ccccc45)nc(-c4ccc5c(c4)sc4ccccc45)n3)cc(-c3ccccc3)c2-n2c3ccccc3c3ccccc32)cc1 ; Cc1ccc2c(c1)c1cc(C)ccc1n2-c1c(-c2ccccc2)cc(-c2nc(-c3ccc4c(c3)oc3ccccc34)nc(-c3ccc4c(c3)sc3ccccc34)n2)cc1-c1ccccc1 ; CC(C)(C)c1ccc2c(c1)c1cc(C(C)(C)C)ccc1n2-c1c(-c2ccccc2)cc(-c2nc(-c3ccc4c(c3)sc3ccccc34)nc(-c3ccc4c(c3)sc3ccccc34)n2)cc1-c1ccccc1]

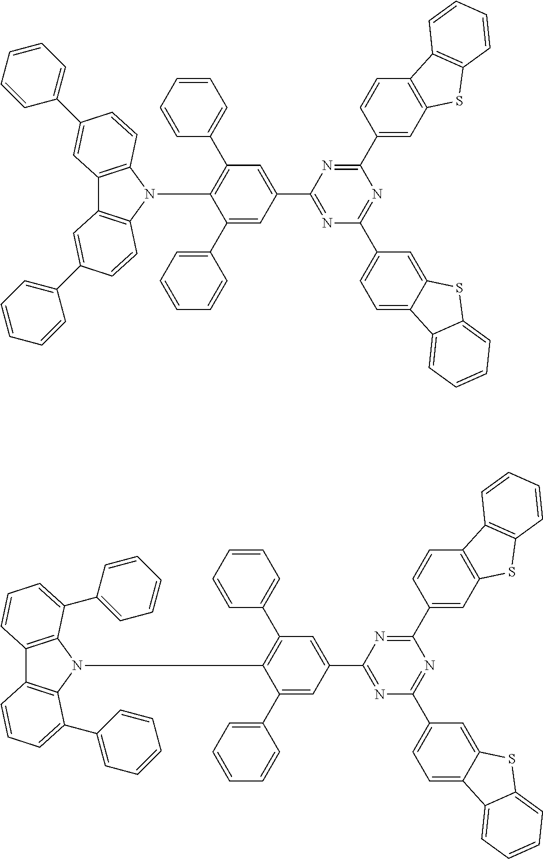 [SMILES: c1ccc(-c2ccc3c(c2)c2cc(-c4ccccc4)ccc2n3-c2c(-c3ccccc3)cc(-c3nc(-c4ccc5c(c4)sc4ccccc45)nc(-c4ccc5c(c4)sc4ccccc45)n3)cc2-c2ccccc2)cc1 ; c1ccc(-c2cc(-c3nc(-c4ccc5c(c4)sc4ccccc45)nc(-c4ccc5c(c4)sc4ccccc45)n3)cc(-c3ccccc3)c2-n2c3c(-c4ccccc4)cccc3c3cccc(-c4ccccc4)c32)cc1]

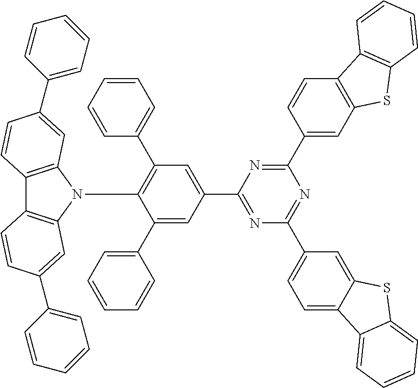 [SMILES: c1ccc(-c2ccc3c4ccc(-c5ccccc5)cc4n(-c4c(-c5ccccc5)cc(-c5nc(-c6ccc7c(c6)sc6ccccc67)nc(-c6ccc7c(c6)sc6ccccc67)n5)cc4-c4ccccc4)c3c2)cc1]

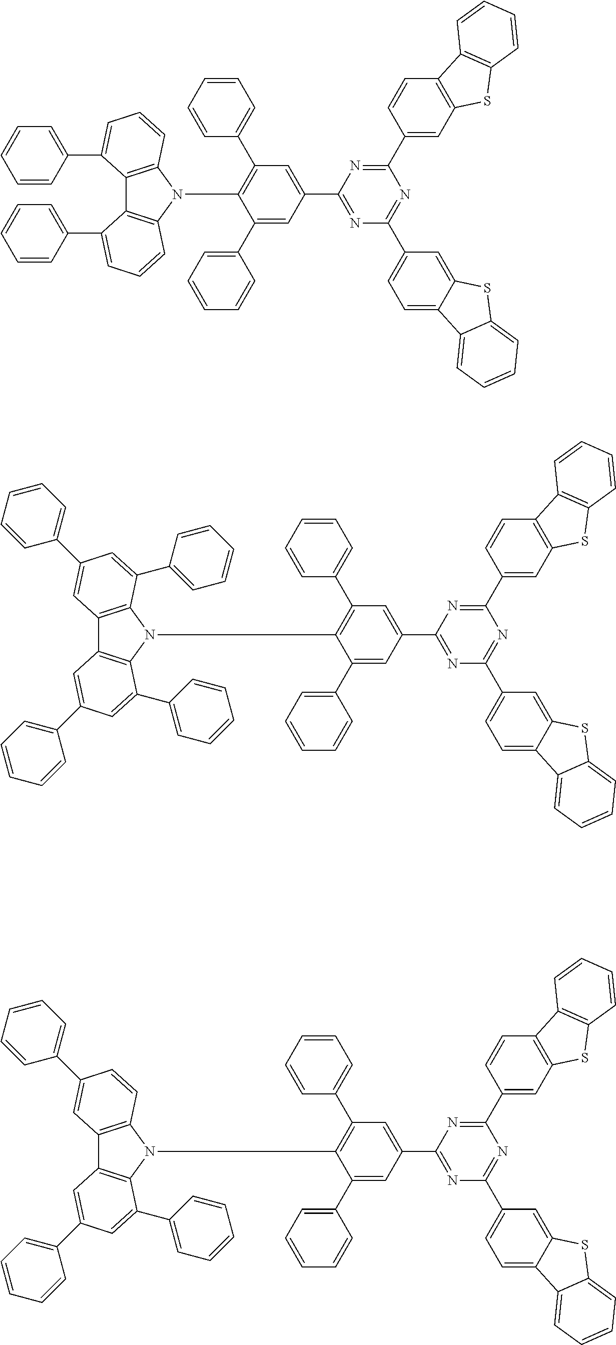 [SMILES: c1ccc(-c2cc(-c3nc(-c4ccc5c(c4)sc4ccccc45)nc(-c4ccc5c(c4)sc4ccccc45)n3)cc(-c3ccccc3)c2-n2c3cccc(-c4ccccc4)c3c3c(-c4ccccc4)cccc32)cc1 ; c1ccc(-c2cc(-c3ccccc3)c3c(c2)c2cc(-c4ccccc4)cc(-c4ccccc4)c2n3-c2c(-c3ccccc3)cc(-c3nc(-c4ccc5c(c4)sc4ccccc45)nc(-c4ccc5c(c4)sc4ccccc45)n3)cc2-c2ccccc2)cc1 ; c1ccc(-c2ccc3c(c2)c2cc(-c4ccccc4)cc(-c4ccccc4)c2n3-c2c(-c3ccccc3)cc(-c3nc(-c4ccc5c(c4)sc4ccccc45)nc(-c4ccc5c(c4)sc4ccccc45)n3)cc2-c2ccccc2)cc1]

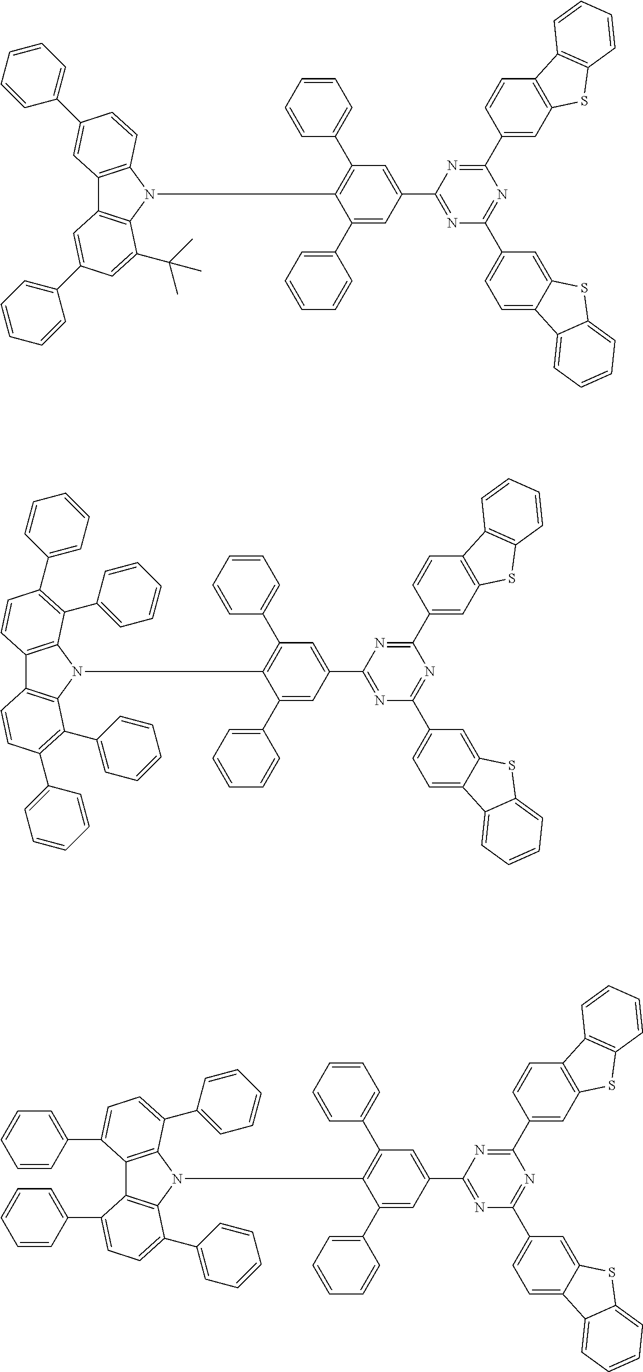 [SMILES: CC(C)(C)c1cc(-c2ccccc2)cc2c3cc(-c4ccccc4)ccc3n(-c3c(-c4ccccc4)cc(-c4nc(-c5ccc6c(c5)sc5ccccc56)nc(-c5ccc6c(c5)sc5ccccc56)n4)cc3-c3ccccc3)c12 ; c1ccc(-c2cc(-c3nc(-c4ccc5c(c4)sc4ccccc45)nc(-c4ccc5c(c4)sc4ccccc45)n3)cc(-c3ccccc3)c2-n2c3c(-c4ccccc4)c(-c4ccccc4)ccc3c3ccc(-c4ccccc4)c(-c4ccccc4)c32)cc1 ; c1ccc(-c2cc(-c3nc(-c4ccc5c(c4)sc4ccccc45)nc(-c4ccc5c(c4)sc4ccccc45)n3)cc(-c3ccccc3)c2-n2c3c(-c4ccccc4)ccc(-c4ccccc4)c3c3c(-c4ccccc4)ccc(-c4ccccc4)c32)cc1]

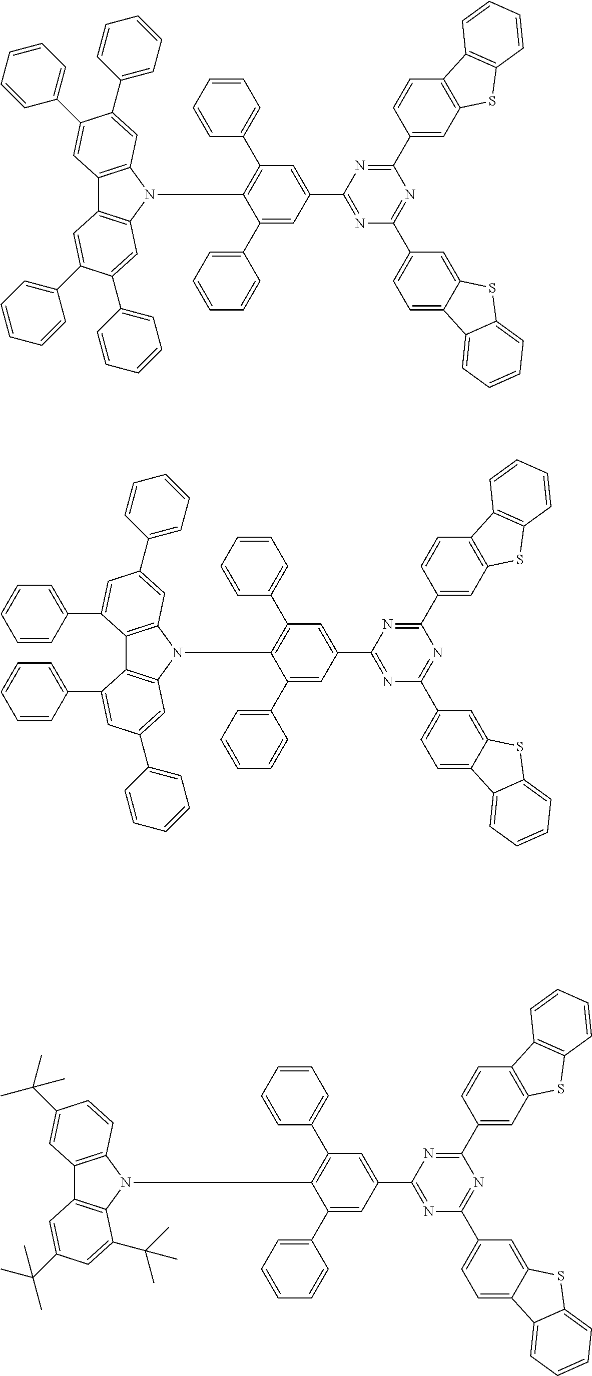 [SMILES: c1ccc(-c2cc3c4cc(-c5ccccc5)c(-c5ccccc5)cc4n(-c4c(-c5ccccc5)cc(-c5nc(-c6ccc7c(c6)sc6ccccc67)nc(-c6ccc7c(c6)sc6ccccc67)n5)cc4-c4ccccc4)c3cc2-c2ccccc2)cc1 ; c1ccc(-c2cc(-c3ccccc3)c3c4c(-c5ccccc5)cc(-c5ccccc5)cc4n(-c4c(-c5ccccc5)cc(-c5nc(-c6ccc7c(c6)sc6ccccc67)nc(-c6ccc7c(c6)sc6ccccc67)n5)cc4-c4ccccc4)c3c2)cc1 ; CC(C)(C)c1ccc2c(c1)c1cc(C(C)(C)C)cc(C(C)(C)C)c1n2-c1c(-c2ccccc2)cc(-c2nc(-c3ccc4c(c3)sc3ccccc34)nc(-c3ccc4c(c3)sc3ccccc34)n2)cc1-c1ccccc1]

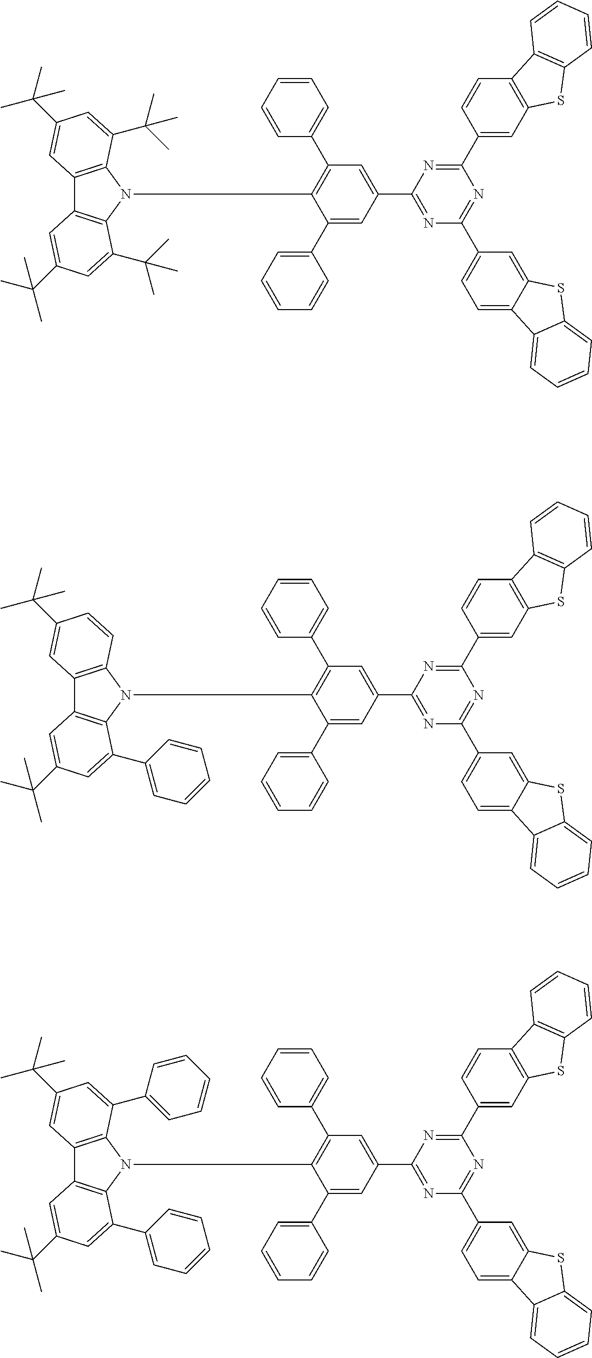 [SMILES: CC(C)(C)c1cc(C(C)(C)C)c2c(c1)c1cc(C(C)(C)C)cc(C(C)(C)C)c1n2-c1c(-c2ccccc2)cc(-c2nc(-c3ccc4c(c3)sc3ccccc34)nc(-c3ccc4c(c3)sc3ccccc34)n2)cc1-c1ccccc1 ; CC(C)(C)c1ccc2c(c1)c1cc(C(C)(C)C)cc(-c3ccccc3)c1n2-c1c(-c2ccccc2)cc(-c2nc(-c3ccc4c(c3)sc3ccccc34)nc(-c3ccc4c(c3)sc3ccccc34)n2)cc1-c1ccccc1 ; CC(C)(C)c1cc(-c2ccccc2)c2c(c1)c1cc(C(C)(C)C)cc(-c3ccccc3)c1n2-c1c(-c2ccccc2)cc(-c2nc(-c3ccc4c(c3)sc3ccccc34)nc(-c3ccc4c(c3)sc3ccccc34)n2)cc1-c1ccccc1]

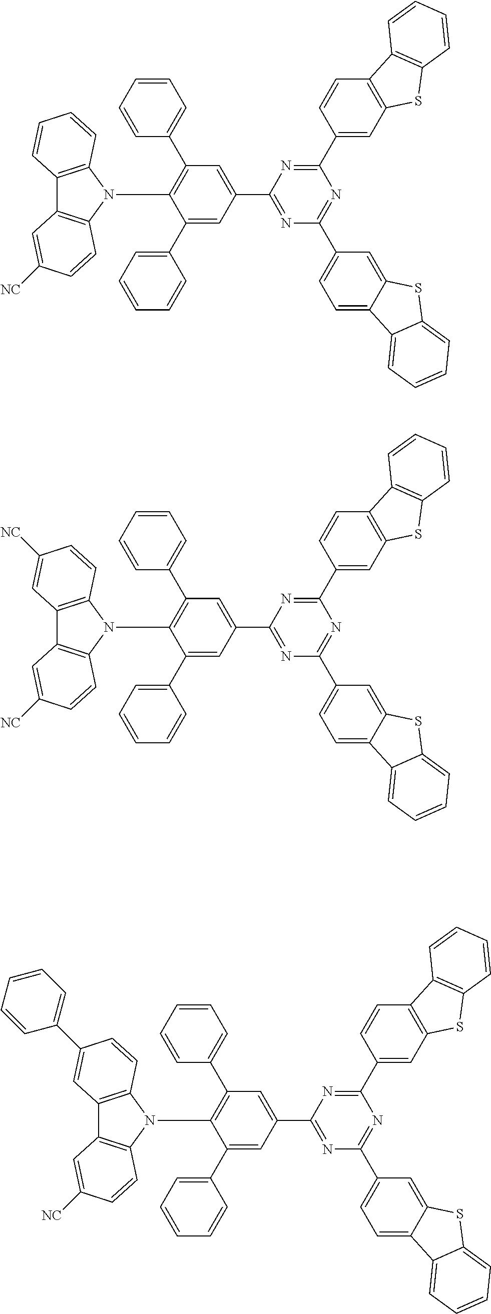 [SMILES: N#Cc1ccc2c(c1)c1ccccc1n2-c1c(-c2ccccc2)cc(-c2nc(-c3ccc4c(c3)sc3ccccc34)nc(-c3ccc4c(c3)sc3ccccc34)n2)cc1-c1ccccc1 ; N#Cc1ccc2c(c1)c1cc(C#N)ccc1n2-c1c(-c2ccccc2)cc(-c2nc(-c3ccc4c(c3)sc3ccccc34)nc(-c3ccc4c(c3)sc3ccccc34)n2)cc1-c1ccccc1 ; N#Cc1ccc2c(c1)c1cc(-c3ccccc3)ccc1n2-c1c(-c2ccccc2)cc(-c2nc(-c3ccc4c(c3)sc3ccccc34)nc(-c3ccc4c(c3)sc3ccccc34)n2)cc1-c1ccccc1]

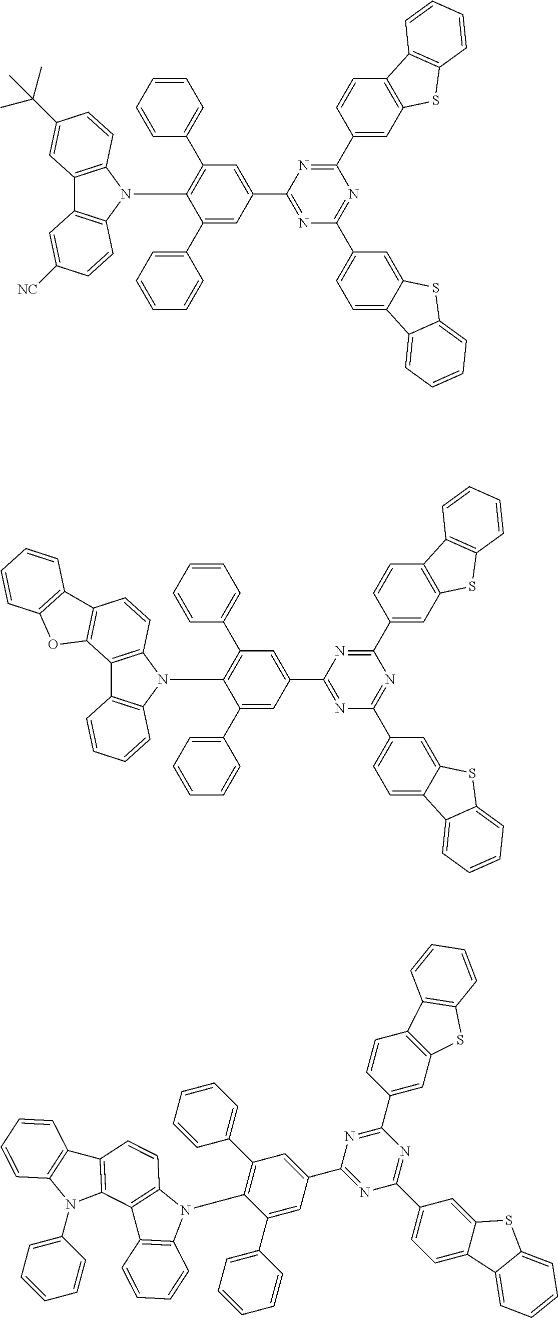 [SMILES: CC(C)(C)c1ccc2c(c1)c1cc(C#N)ccc1n2-c1c(-c2ccccc2)cc(-c2nc(-c3ccc4c(c3)sc3ccccc34)nc(-c3ccc4c(c3)sc3ccccc34)n2)cc1-c1ccccc1 ; c1ccc(-c2cc(-c3nc(-c4ccc5c(c4)sc4ccccc45)nc(-c4ccc5c(c4)sc4ccccc45)n3)cc(-c3ccccc3)c2-n2c3ccccc3c3c4oc5ccccc5c4ccc32)cc1 ; c1ccc(-c2cc(-c3nc(-c4ccc5c(c4)sc4ccccc45)nc(-c4ccc5c(c4)sc4ccccc45)n3)cc(-c3ccccc3)c2-n2c3ccccc3c3c2ccc2c4ccccc4n(-c4ccccc4)c23)cc1]

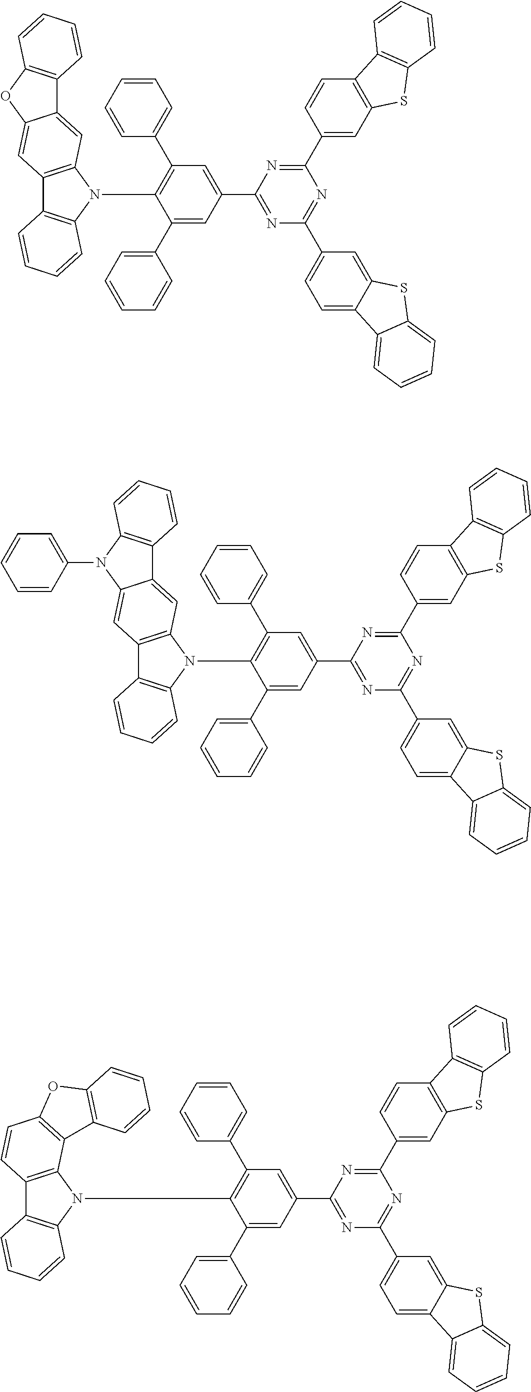 [SMILES: c1ccc(-c2cc(-c3nc(-c4ccc5c(c4)sc4ccccc45)nc(-c4ccc5c(c4)sc4ccccc45)n3)cc(-c3ccccc3)c2-n2c3ccccc3c3cc4oc5ccccc5c4cc32)cc1 ; c1ccc(-c2cc(-c3nc(-c4ccc5c(c4)sc4ccccc45)nc(-c4ccc5c(c4)sc4ccccc45)n3)cc(-c3ccccc3)c2-n2c3ccccc3c3cc4c(cc32)c2ccccc2n4-c2ccccc2)cc1 ; c1ccc(-c2cc(-c3nc(-c4ccc5c(c4)sc4ccccc45)nc(-c4ccc5c(c4)sc4ccccc45)n3)cc(-c3ccccc3)c2-n2c3ccccc3c3ccc4oc5ccccc5c4c32)cc1]

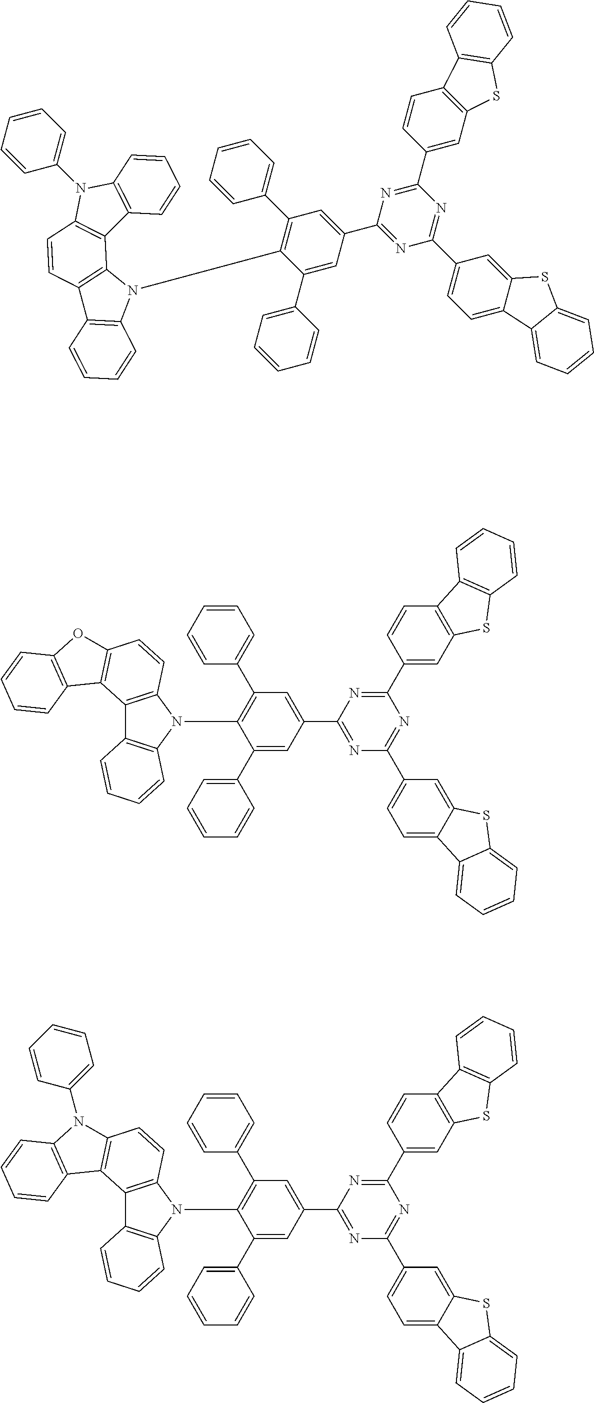 [SMILES: c1ccc(-c2cc(-c3nc(-c4ccc5c(c4)sc4ccccc45)nc(-c4ccc5c(c4)sc4ccccc45)n3)cc(-c3ccccc3)c2-n2c3ccccc3c3ccc4c(c5ccccc5n4-c4ccccc4)c32)cc1 ; c1ccc(-c2cc(-c3nc(-c4ccc5c(c4)sc4ccccc45)nc(-c4ccc5c(c4)sc4ccccc45)n3)cc(-c3ccccc3)c2-n2c3ccccc3c3c4c(ccc32)oc2ccccc24)cc1 ; c1ccc(-c2cc(-c3nc(-c4ccc5c(c4)sc4ccccc45)nc(-c4ccc5c(c4)sc4ccccc45)n3)cc(-c3ccccc3)c2-n2c3ccccc3c3c4c5ccccc5n(-c5ccccc5)c4ccc32)cc1]

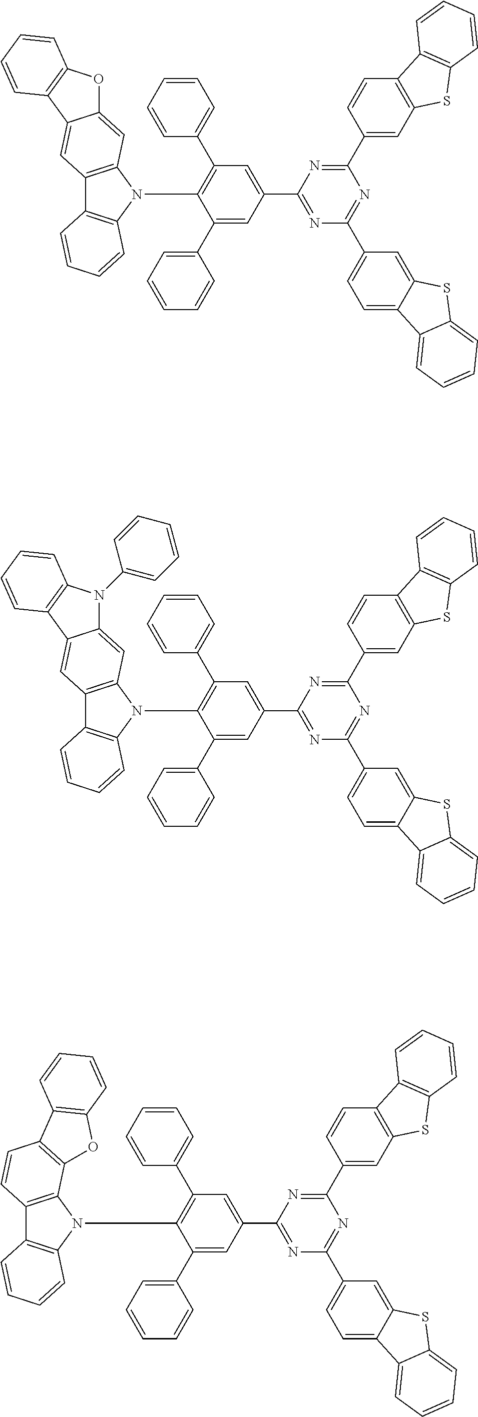 [SMILES: c1ccc(-c2cc(-c3nc(-c4ccc5c(c4)sc4ccccc45)nc(-c4ccc5c(c4)sc4ccccc45)n3)cc(-c3ccccc3)c2-n2c3ccccc3c3cc4c(cc32)oc2ccccc24)cc1 ; c1ccc(-c2cc(-c3nc(-c4ccc5c(c4)sc4ccccc45)nc(-c4ccc5c(c4)sc4ccccc45)n3)cc(-c3ccccc3)c2-n2c3ccccc3c3cc4c5ccccc5n(-c5ccccc5)c4cc32)cc1 ; c1ccc(-c2cc(-c3nc(-c4ccc5c(c4)sc4ccccc45)nc(-c4ccc5c(c4)sc4ccccc45)n3)cc(-c3ccccc3)c2-n2c3ccccc3c3ccc4c5ccccc5oc4c32)cc1]

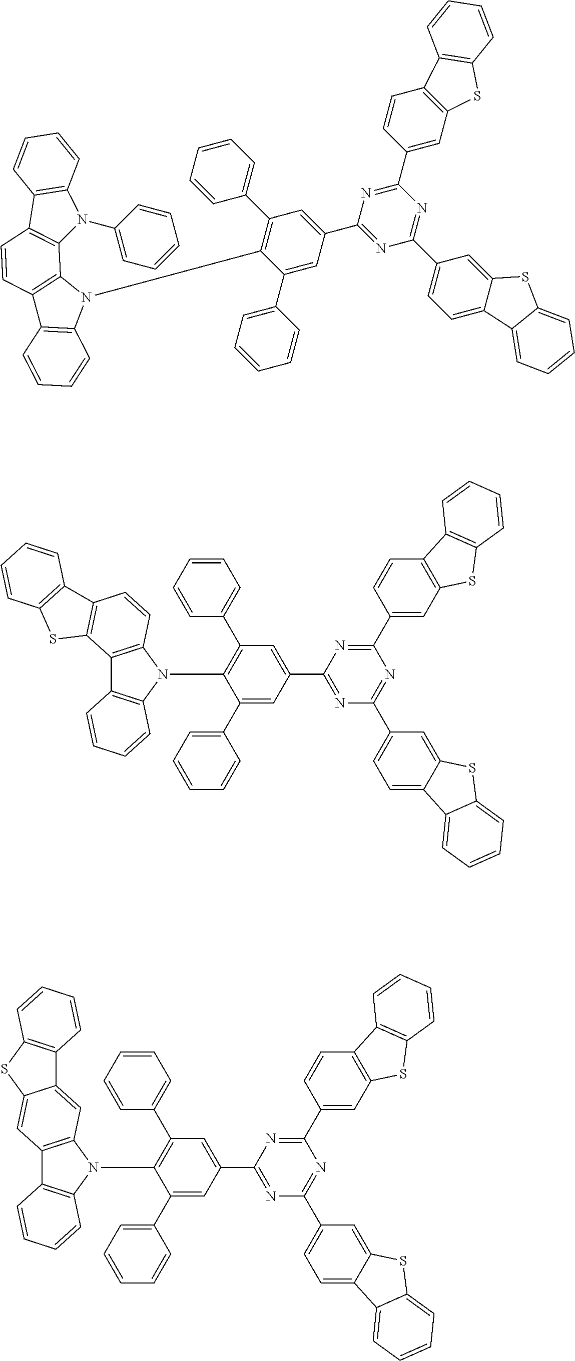 [SMILES: c1ccc(-c2cc(-c3nc(-c4ccc5c(c4)sc4ccccc45)nc(-c4ccc5c(c4)sc4ccccc45)n3)cc(-c3ccccc3)c2-n2c3ccccc3c3ccc4c5ccccc5n(-c5ccccc5)c4c32)cc1 ; c1ccc(-c2cc(-c3nc(-c4ccc5c(c4)sc4ccccc45)nc(-c4ccc5c(c4)sc4ccccc45)n3)cc(-c3ccccc3)c2-n2c3ccccc3c3c4sc5ccccc5c4ccc32)cc1 ; c1ccc(-c2cc(-c3nc(-c4ccc5c(c4)sc4ccccc45)nc(-c4ccc5c(c4)sc4ccccc45)n3)cc(-c3ccccc3)c2-n2c3ccccc3c3cc4sc5ccccc5c4cc32)cc1]

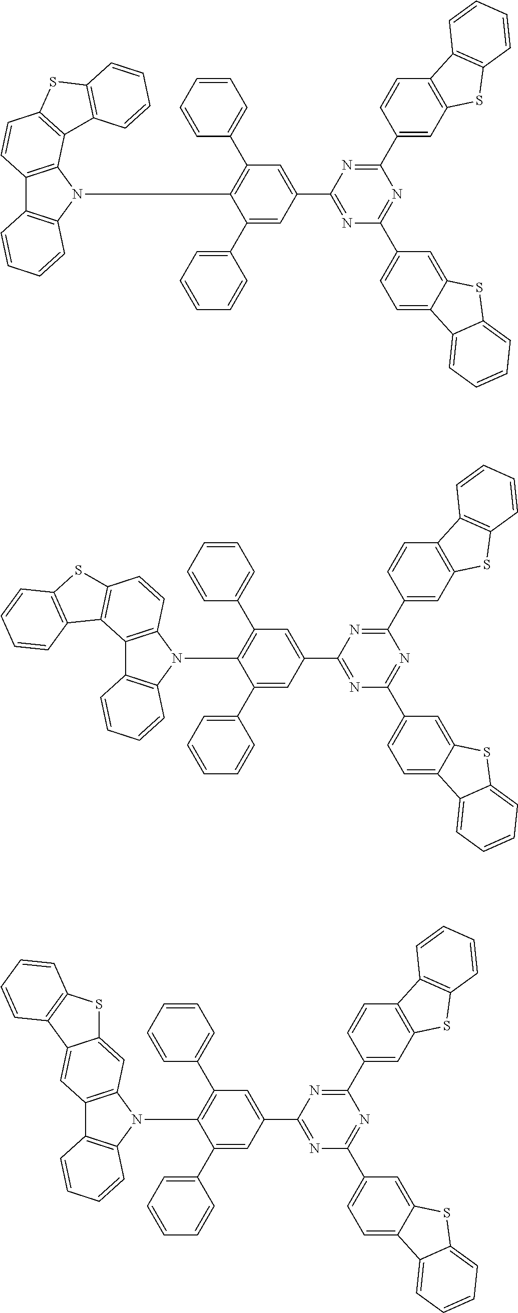 [SMILES: c1ccc(-c2cc(-c3nc(-c4ccc5c(c4)sc4ccccc45)nc(-c4ccc5c(c4)sc4ccccc45)n3)cc(-c3ccccc3)c2-n2c3ccccc3c3ccc4sc5ccccc5c4c32)cc1 ; c1ccc(-c2cc(-c3nc(-c4ccc5c(c4)sc4ccccc45)nc(-c4ccc5c(c4)sc4ccccc45)n3)cc(-c3ccccc3)c2-n2c3ccccc3c3c4c(ccc32)sc2ccccc24)cc1 ; c1ccc(-c2cc(-c3nc(-c4ccc5c(c4)sc4ccccc45)nc(-c4ccc5c(c4)sc4ccccc45)n3)cc(-c3ccccc3)c2-n2c3ccccc3c3cc4c(cc32)sc2ccccc24)cc1]

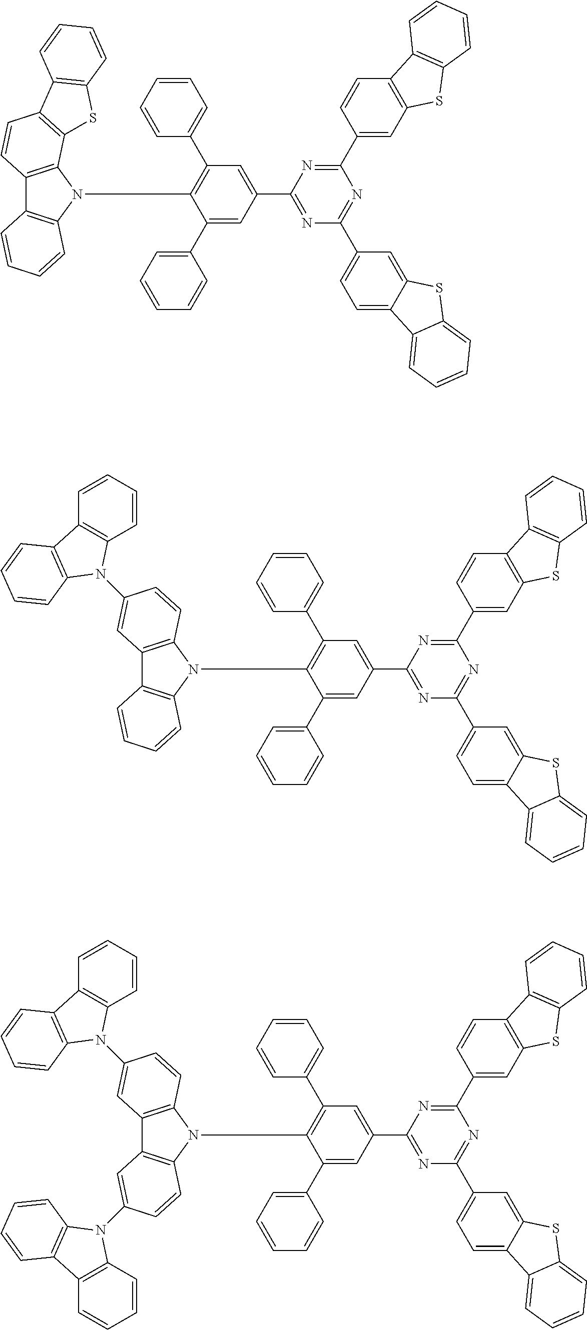 [SMILES: c1ccc(-c2cc(-c3nc(-c4ccc5c(c4)sc4ccccc45)nc(-c4ccc5c(c4)sc4ccccc45)n3)cc(-c3ccccc3)c2-n2c3ccccc3c3ccc4c5ccccc5sc4c32)cc1 ; c1ccc(-c2cc(-c3nc(-c4ccc5c(c4)sc4ccccc45)nc(-c4ccc5c(c4)sc4ccccc45)n3)cc(-c3ccccc3)c2-n2c3ccccc3c3cc(-n4c5ccccc5c5ccccc54)ccc32)cc1 ; c1ccc(-c2cc(-c3nc(-c4ccc5c(c4)sc4ccccc45)nc(-c4ccc5c(c4)sc4ccccc45)n3)cc(-c3ccccc3)c2-n2c3ccc(-n4c5ccccc5c5ccccc54)cc3c3cc(-n4c5ccccc5c5ccccc54)ccc32)cc1]

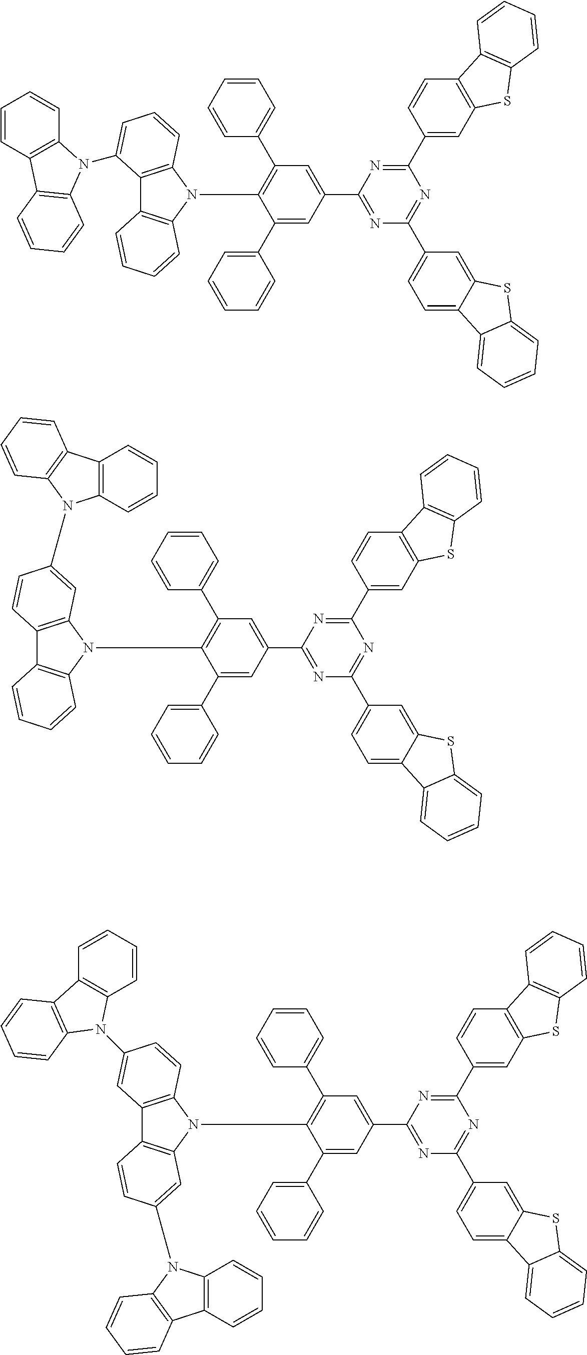 [SMILES: c1ccc(-c2cc(-c3nc(-c4ccc5c(c4)sc4ccccc45)nc(-c4ccc5c(c4)sc4ccccc45)n3)cc(-c3ccccc3)c2-n2c3ccccc3c3c(-n4c5ccccc5c5ccccc54)cccc32)cc1 ; c1ccc(-c2cc(-c3nc(-c4ccc5c(c4)sc4ccccc45)nc(-c4ccc5c(c4)sc4ccccc45)n3)cc(-c3ccccc3)c2-n2c3ccccc3c3ccc(-n4c5ccccc5c5ccccc54)cc32)cc1 ; c1ccc(-c2cc(-c3nc(-c4ccc5c(c4)sc4ccccc45)nc(-c4ccc5c(c4)sc4ccccc45)n3)cc(-c3ccccc3)c2-n2c3ccc(-n4c5ccccc5c5ccccc54)cc3c3ccc(-n4c5ccccc5c5ccccc54)cc32)cc1]

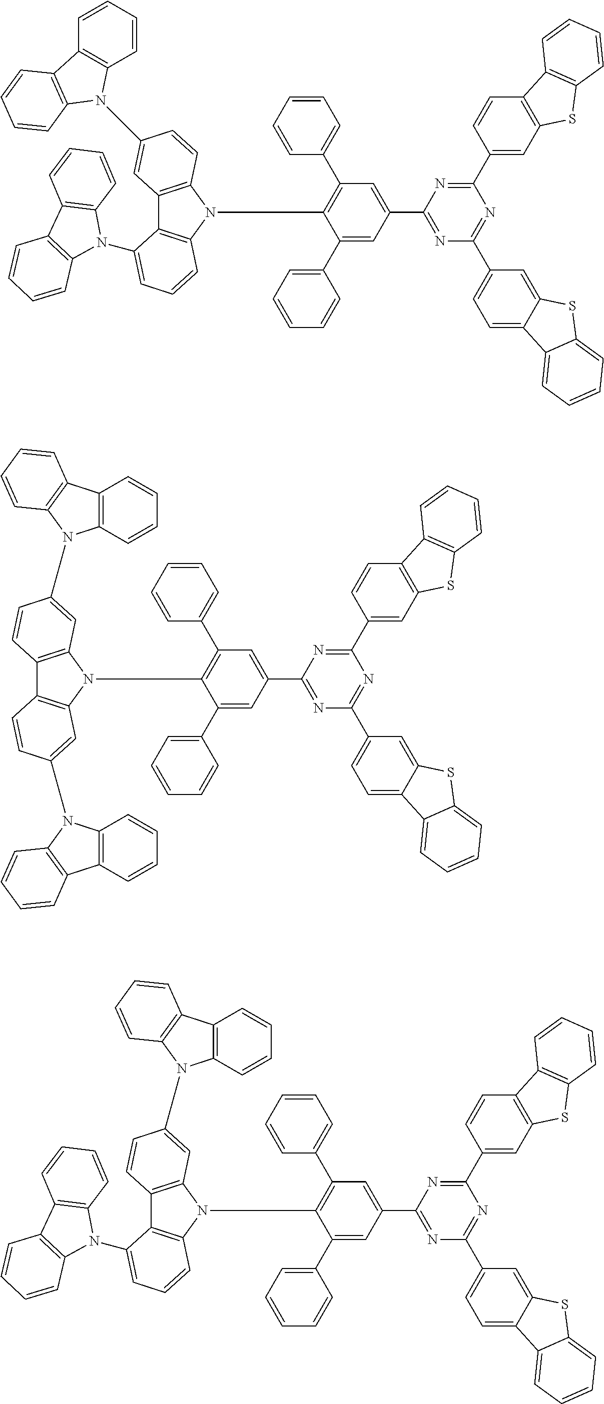 [SMILES: c1ccc(-c2cc(-c3nc(-c4ccc5c(c4)sc4ccccc45)nc(-c4ccc5c(c4)sc4ccccc45)n3)cc(-c3ccccc3)c2-n2c3ccc(-n4c5ccccc5c5ccccc54)cc3c3c(-n4c5ccccc5c5ccccc54)cccc32)cc1 ; c1ccc(-c2cc(-c3nc(-c4ccc5c(c4)sc4ccccc45)nc(-c4ccc5c(c4)sc4ccccc45)n3)cc(-c3ccccc3)c2-n2c3cc(-n4c5ccccc5c5ccccc54)ccc3c3ccc(-n4c5ccccc5c5ccccc54)cc32)cc1 ; c1ccc(-c2cc(-c3nc(-c4ccc5c(c4)sc4ccccc45)nc(-c4ccc5c(c4)sc4ccccc45)n3)cc(-c3ccccc3)c2-n2c3cc(-n4c5ccccc5c5ccccc54)ccc3c3c(-n4c5ccccc5c5ccccc54)cccc32)cc1]

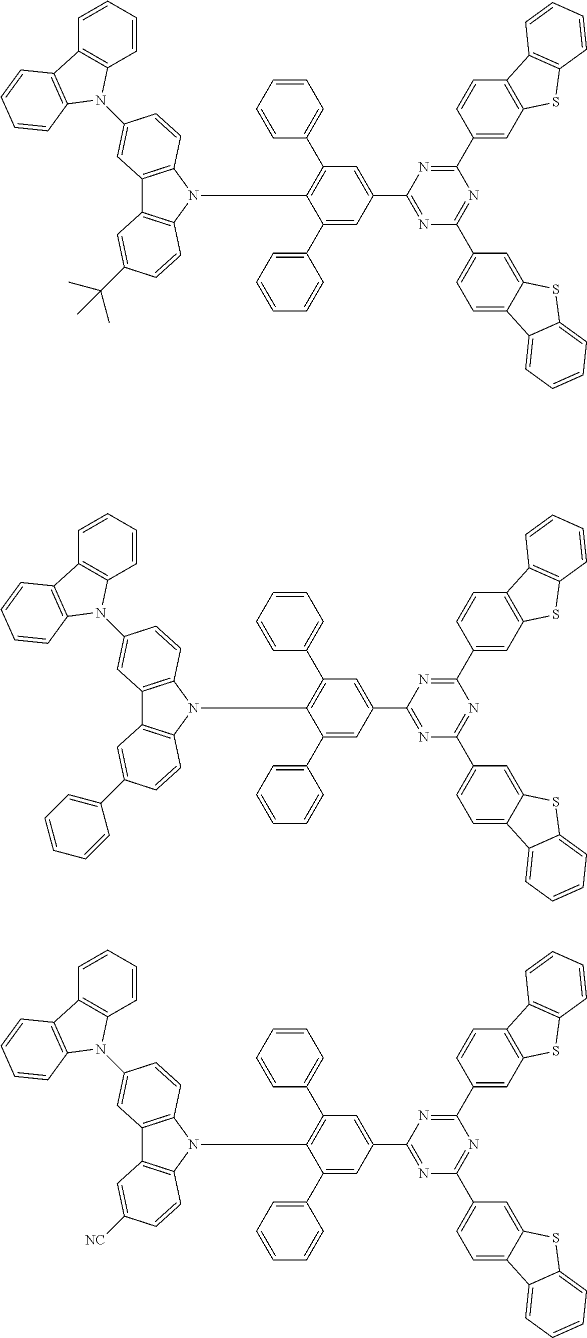 [SMILES: CC(C)(C)c1ccc2c(c1)c1cc(-n3c4ccccc4c4ccccc43)ccc1n2-c1c(-c2ccccc2)cc(-c2nc(-c3ccc4c(c3)sc3ccccc34)nc(-c3ccc4c(c3)sc3ccccc34)n2)cc1-c1ccccc1 ; c1ccc(-c2ccc3c(c2)c2cc(-n4c5ccccc5c5ccccc54)ccc2n3-c2c(-c3ccccc3)cc(-c3nc(-c4ccc5c(c4)sc4ccccc45)nc(-c4ccc5c(c4)sc4ccccc45)n3)cc2-c2ccccc2)cc1 ; N#Cc1ccc2c(c1)c1cc(-n3c4ccccc4c4ccccc43)ccc1n2-c1c(-c2ccccc2)cc(-c2nc(-c3ccc4c(c3)sc3ccccc34)nc(-c3ccc4c(c3)sc3ccccc34)n2)cc1-c1ccccc1]

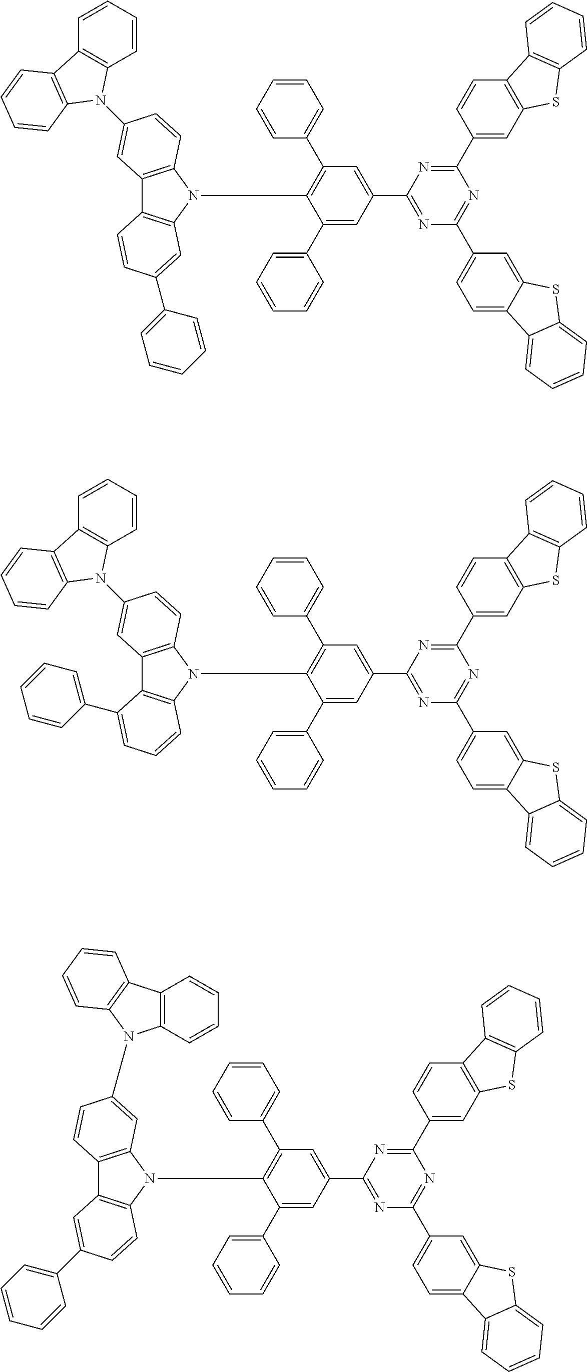 [SMILES: c1ccc(-c2ccc3c4cc(-n5c6ccccc6c6ccccc65)ccc4n(-c4c(-c5ccccc5)cc(-c5nc(-c6ccc7c(c6)sc6ccccc67)nc(-c6ccc7c(c6)sc6ccccc67)n5)cc4-c4ccccc4)c3c2)cc1 ; c1ccc(-c2cc(-c3nc(-c4ccc5c(c4)sc4ccccc45)nc(-c4ccc5c(c4)sc4ccccc45)n3)cc(-c3ccccc3)c2-n2c3ccc(-n4c5ccccc5c5ccccc54)cc3c3c(-c4ccccc4)cccc32)cc1 ; c1ccc(-c2ccc3c(c2)c2ccc(-n4c5ccccc5c5ccccc54)cc2n3-c2c(-c3ccccc3)cc(-c3nc(-c4ccc5c(c4)sc4ccccc45)nc(-c4ccc5c(c4)sc4ccccc45)n3)cc2-c2ccccc2)cc1]

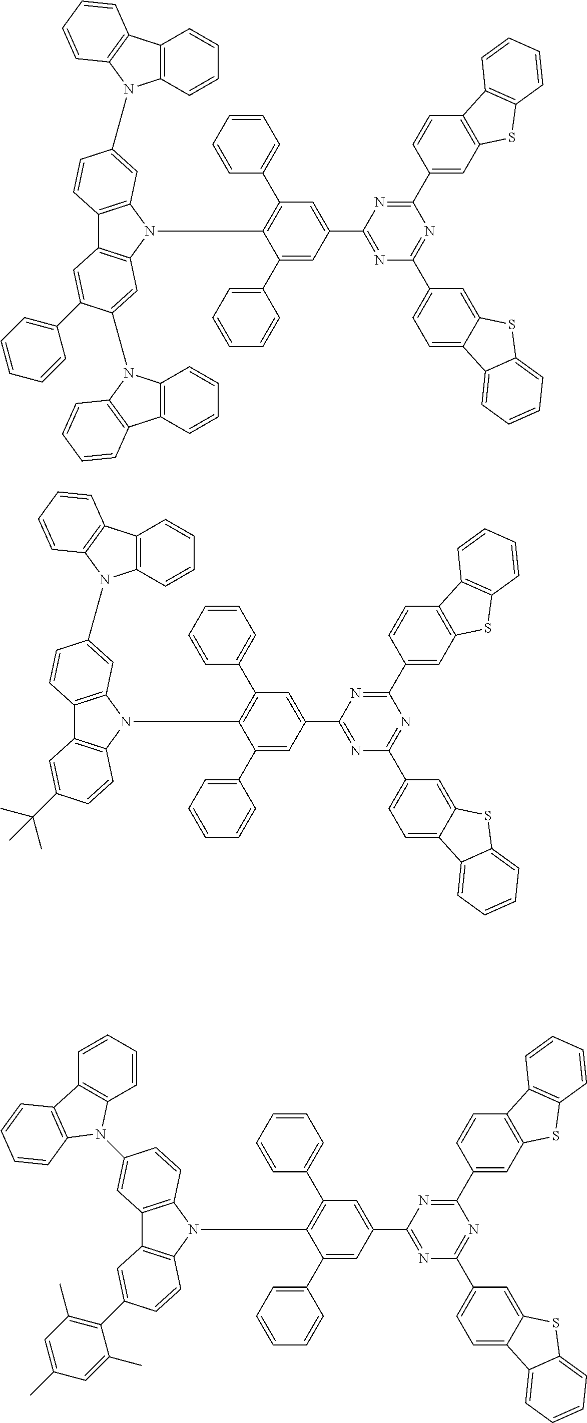

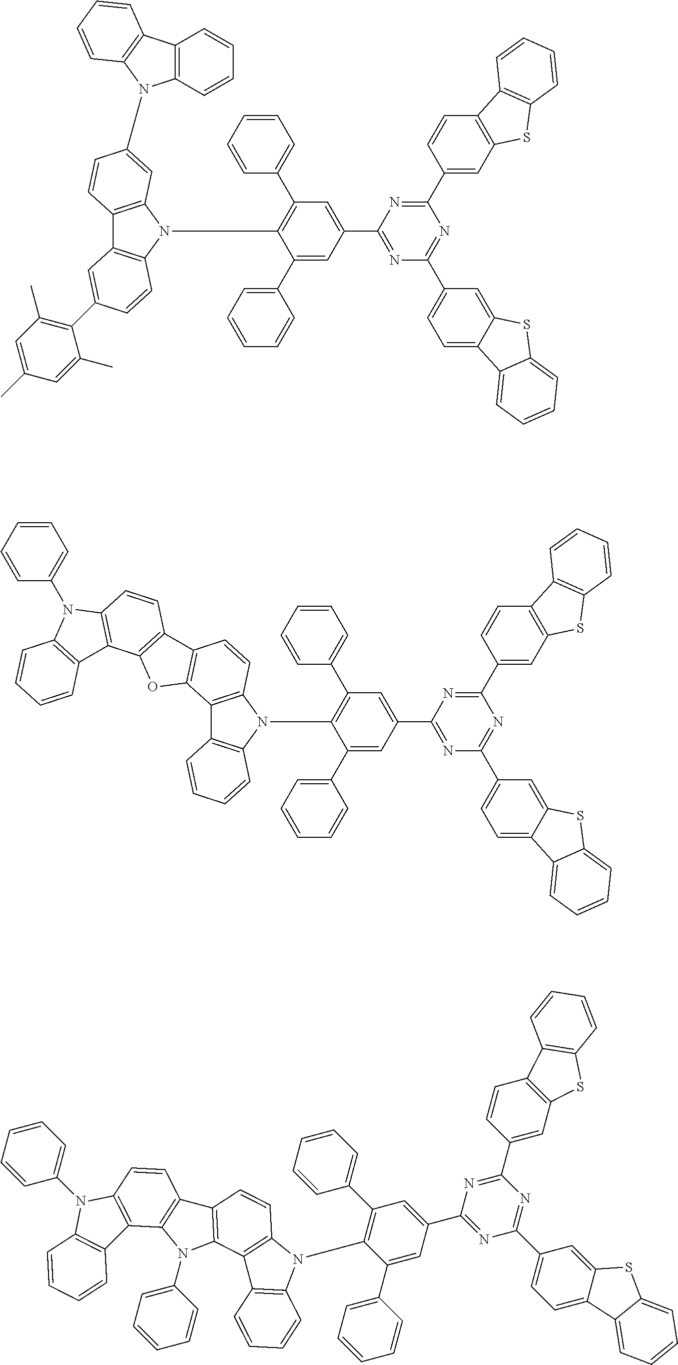 [SMILES: Cc1cc(C)c(-c2ccc3c(c2)c2ccc(-n4c5ccccc5c5ccccc54)cc2n3-c2c(-c3ccccc3)cc(-c3nc(-c4ccc5c(c4)sc4ccccc45)nc(-c4ccc5c(c4)sc4ccccc45)n3)cc2-c2ccccc2)c(C)c1 ; c1ccc(-c2cc(-c3nc(-c4ccc5c(c4)sc4ccccc45)nc(-c4ccc5c(c4)sc4ccccc45)n3)cc(-c3ccccc3)c2-n2c3ccccc3c3c4oc5c(ccc6c5c5ccccc5n6-c5ccccc5)c4ccc32)cc1 ; c1ccc(-c2cc(-c3nc(-c4ccc5c(c4)sc4ccccc45)nc(-c4ccc5c(c4)sc4ccccc45)n3)cc(-c3ccccc3)c2-n2c3ccccc3c3c2ccc2c4ccc5c(c6ccccc6n5-c5ccccc5)c4n(-c4ccccc4)c23)cc1]

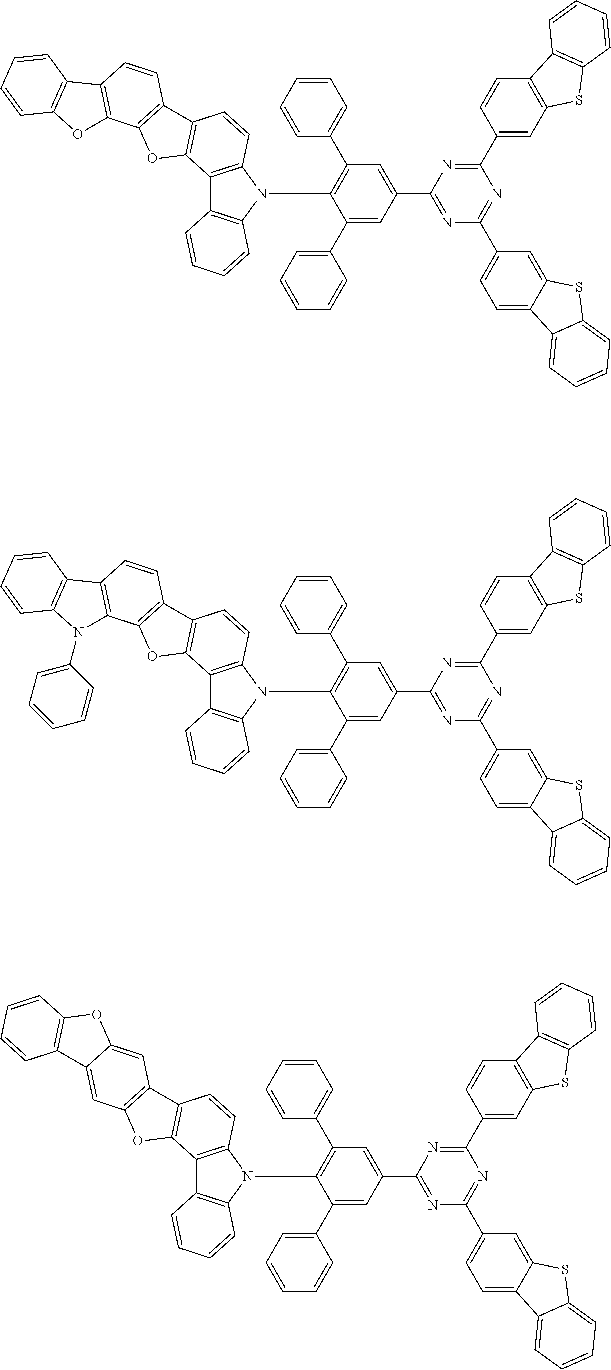 [SMILES: c1ccc(-c2cc(-c3nc(-c4ccc5c(c4)sc4ccccc45)nc(-c4ccc5c(c4)sc4ccccc45)n3)cc(-c3ccccc3)c2-n2c3ccccc3c3c4oc5c(ccc6c7ccccc7oc65)c4ccc32)cc1 ; c1ccc(-c2cc(-c3nc(-c4ccc5c(c4)sc4ccccc45)nc(-c4ccc5c(c4)sc4ccccc45)n3)cc(-c3ccccc3)c2-n2c3ccccc3c3c4oc5c(ccc6c7ccccc7n(-c7ccccc7)c65)c4ccc32)cc1 ; c1ccc(-c2cc(-c3nc(-c4ccc5c(c4)sc4ccccc45)nc(-c4ccc5c(c4)sc4ccccc45)n3)cc(-c3ccccc3)c2-n2c3ccccc3c3c4oc5cc6c(cc5c4ccc32)oc2ccccc26)cc1]

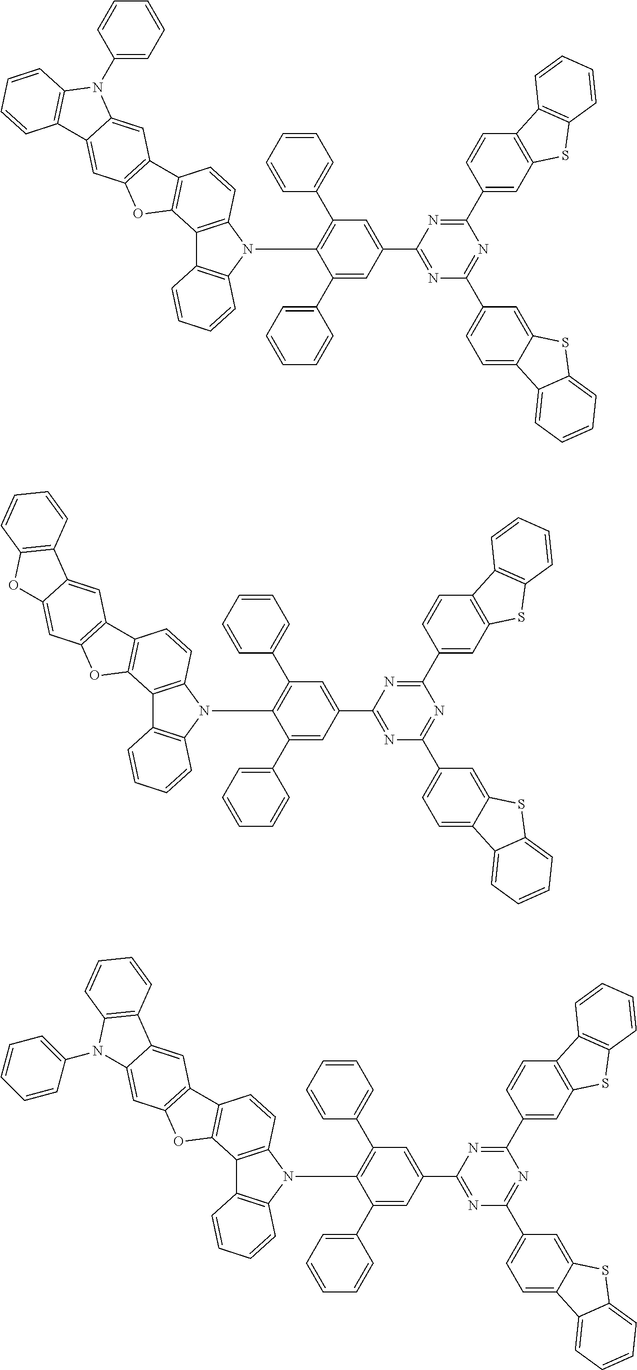 [SMILES: c1ccc(-c2cc(-c3nc(-c4ccc5c(c4)sc4ccccc45)nc(-c4ccc5c(c4)sc4ccccc45)n3)cc(-c3ccccc3)c2-n2c3ccccc3c3c4oc5cc6c7ccccc7n(-c7ccccc7)c6cc5c4ccc32)cc1 ; c1ccc(-c2cc(-c3nc(-c4ccc5c(c4)sc4ccccc45)nc(-c4ccc5c(c4)sc4ccccc45)n3)cc(-c3ccccc3)c2-n2c3ccccc3c3c4oc5cc6oc7ccccc7c6cc5c4ccc32)cc1 ; c1ccc(-c2cc(-c3nc(-c4ccc5c(c4)sc4ccccc45)nc(-c4ccc5c(c4)sc4ccccc45)n3)cc(-c3ccccc3)c2-n2c3ccccc3c3c4oc5cc6c(cc5c4ccc32)c2ccccc2n6-c2ccccc2)cc1]

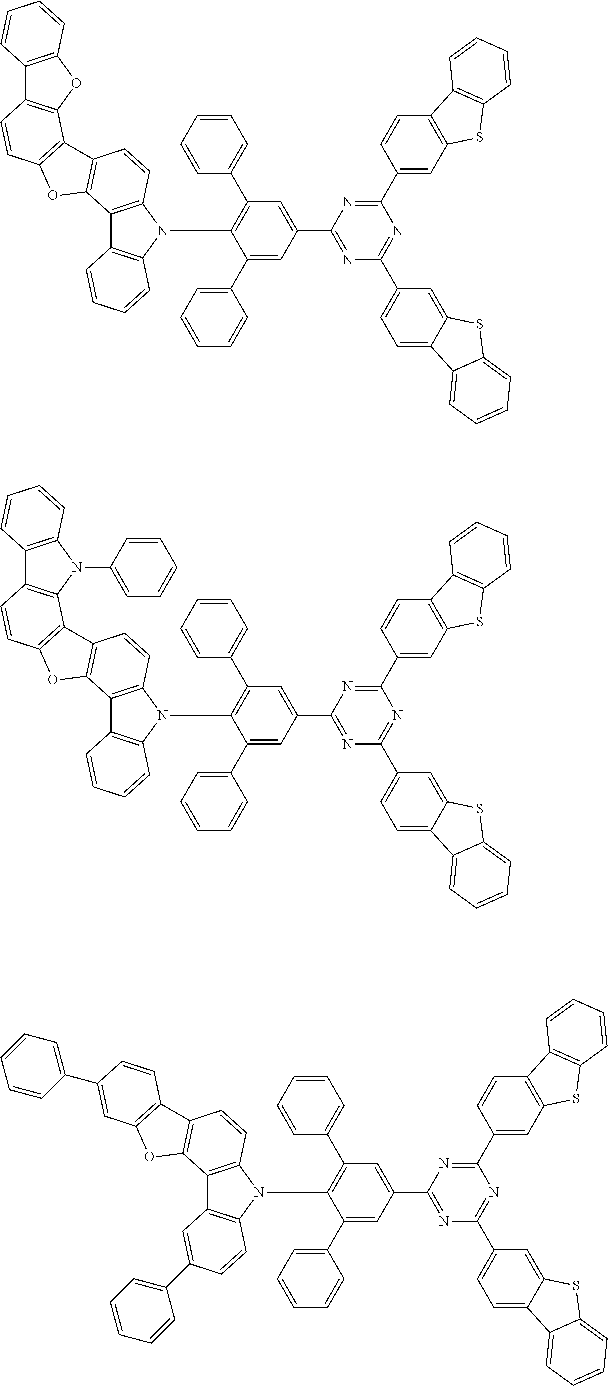 [SMILES: c1ccc(-c2cc(-c3nc(-c4ccc5c(c4)sc4ccccc45)nc(-c4ccc5c(c4)sc4ccccc45)n3)cc(-c3ccccc3)c2-n2c3ccccc3c3c4oc5ccc6c7ccccc7oc6c5c4ccc32)cc1 ; c1ccc(-c2cc(-c3nc(-c4ccc5c(c4)sc4ccccc45)nc(-c4ccc5c(c4)sc4ccccc45)n3)cc(-c3ccccc3)c2-n2c3ccccc3c3c4oc5ccc6c7ccccc7n(-c7ccccc7)c6c5c4ccc32)cc1 ; c1ccc(-c2ccc3c(c2)oc2c3ccc3c2c2cc(-c4ccccc4)ccc2n3-c2c(-c3ccccc3)cc(-c3nc(-c4ccc5c(c4)sc4ccccc45)nc(-c4ccc5c(c4)sc4ccccc45)n3)cc2-c2ccccc2)cc1]

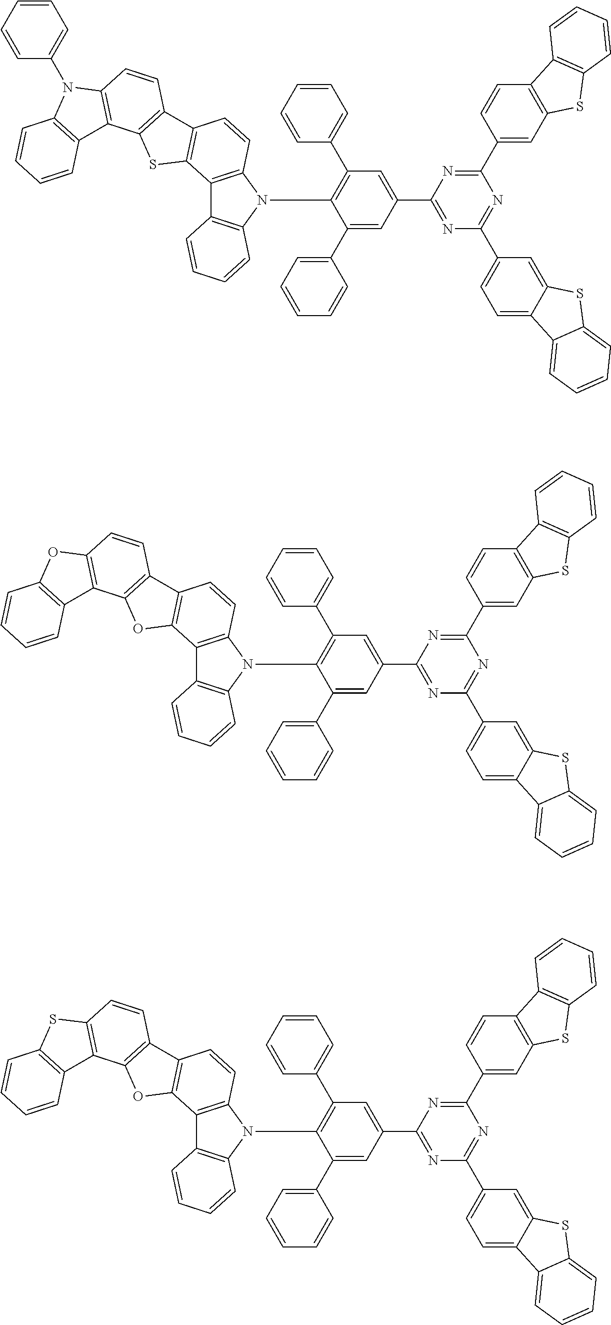 [SMILES: c1ccc(-c2cc(-c3nc(-c4ccc5c(c4)sc4ccccc45)nc(-c4ccc5c(c4)sc4ccccc45)n3)cc(-c3ccccc3)c2-n2c3ccccc3c3c4sc5c(ccc6c5c5ccccc5n6-c5ccccc5)c4ccc32)cc1 ; c1ccc(-c2cc(-c3nc(-c4ccc5c(c4)sc4ccccc45)nc(-c4ccc5c(c4)sc4ccccc45)n3)cc(-c3ccccc3)c2-n2c3ccccc3c3c4oc5c(ccc6oc7ccccc7c65)c4ccc32)cc1 ; c1ccc(-c2cc(-c3nc(-c4ccc5c(c4)sc4ccccc45)nc(-c4ccc5c(c4)sc4ccccc45)n3)cc(-c3ccccc3)c2-n2c3ccccc3c3c4oc5c(ccc6sc7ccccc7c65)c4ccc32)cc1]

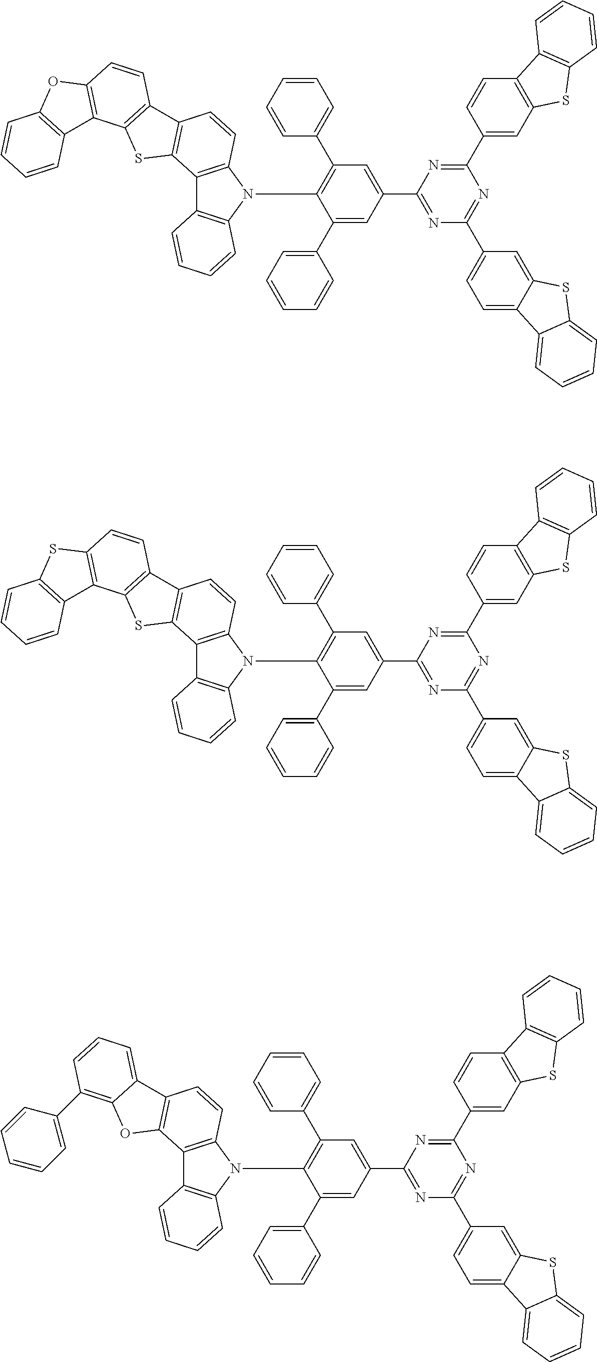 [SMILES: c1ccc(-c2cc(-c3nc(-c4ccc5c(c4)sc4ccccc45)nc(-c4ccc5c(c4)sc4ccccc45)n3)cc(-c3ccccc3)c2-n2c3ccccc3c3c4sc5c(ccc6oc7ccccc7c65)c4ccc32)cc1 ; c1ccc(-c2cc(-c3nc(-c4ccc5c(c4)sc4ccccc45)nc(-c4ccc5c(c4)sc4ccccc45)n3)cc(-c3ccccc3)c2-n2c3ccccc3c3c4sc5c(ccc6sc7ccccc7c65)c4ccc32)cc1 ; c1ccc(-c2cc(-c3nc(-c4ccc5c(c4)sc4ccccc45)nc(-c4ccc5c(c4)sc4ccccc45)n3)cc(-c3ccccc3)c2-n2c3ccccc3c3c4oc5c(-c6ccccc6)cccc5c4ccc32)cc1]

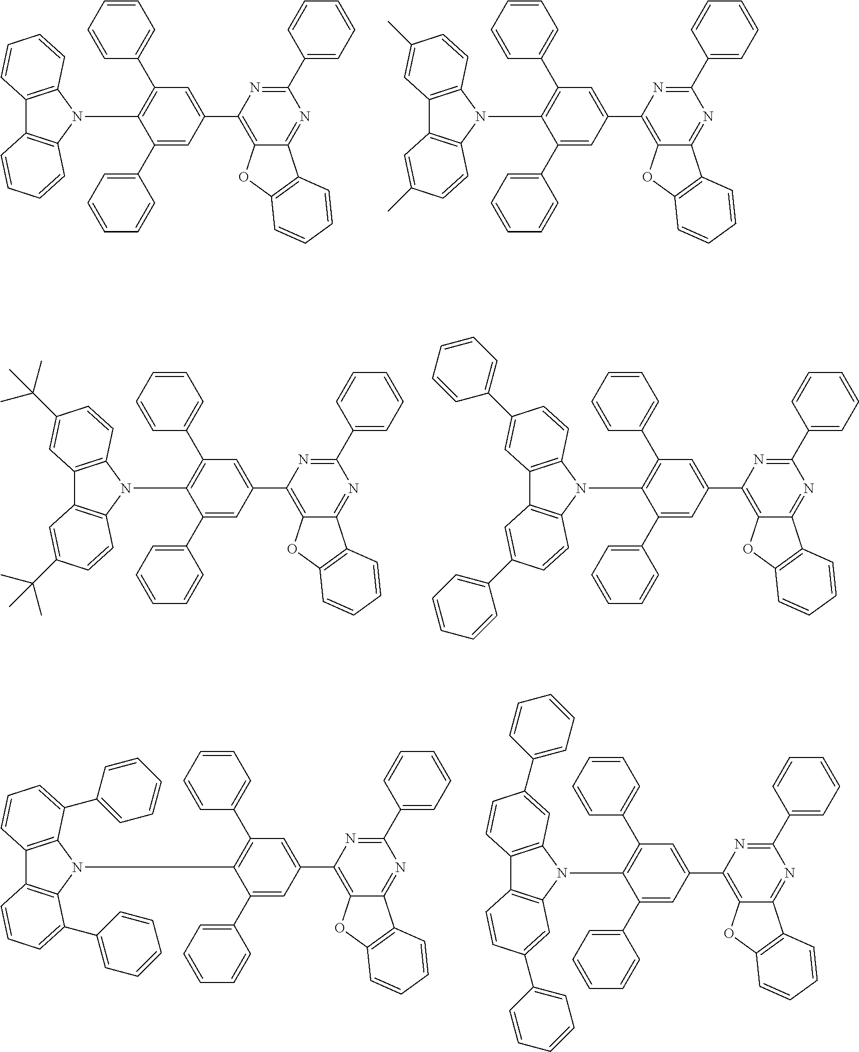

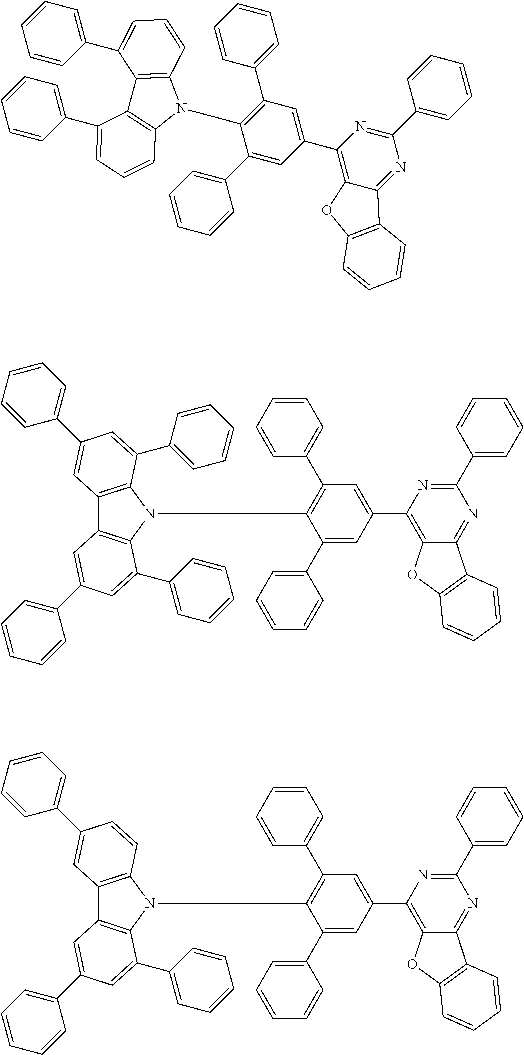 [SMILES: c1ccc(-c2nc(-c3cc(-c4ccccc4)c(-n4c5cccc(-c6ccccc6)c5c5c(-c6ccccc6)cccc54)c(-c4ccccc4)c3)c3oc4ccccc4c3n2)cc1 ; c1ccc(-c2cc(-c3ccccc3)c3c(c2)c2cc(-c4ccccc4)cc(-c4ccccc4)c2n3-c2c(-c3ccccc3)cc(-c3nc(-c4ccccc4)nc4c3oc3ccccc34)cc2-c2ccccc2)cc1 ; c1ccc(-c2ccc3c(c2)c2cc(-c4ccccc4)cc(-c4ccccc4)c2n3-c2c(-c3ccccc3)cc(-c3nc(-c4ccccc4)nc4c3oc3ccccc34)cc2-c2ccccc2)cc1]

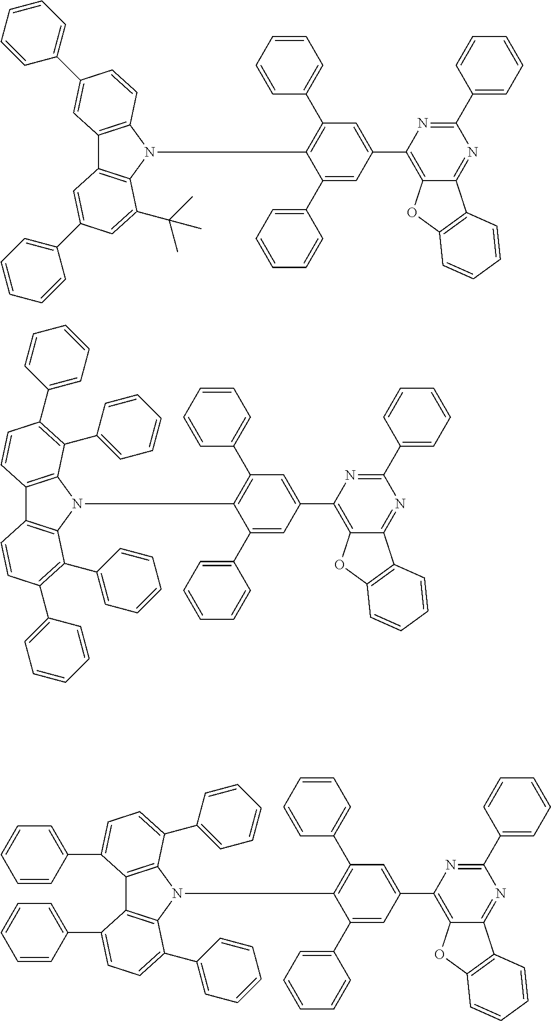

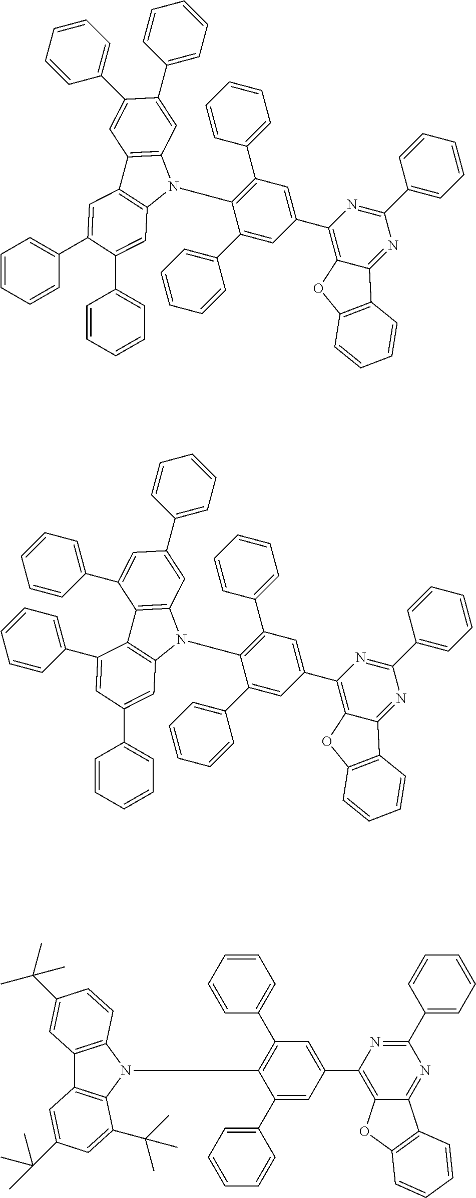 [SMILES: c1ccc(-c2nc(-c3cc(-c4ccccc4)c(-n4c5cc(-c6ccccc6)c(-c6ccccc6)cc5c5cc(-c6ccccc6)c(-c6ccccc6)cc54)c(-c4ccccc4)c3)c3oc4ccccc4c3n2)cc1 ; c1ccc(-c2cc(-c3ccccc3)c3c4c(-c5ccccc5)cc(-c5ccccc5)cc4n(-c4c(-c5ccccc5)cc(-c5nc(-c6ccccc6)nc6c5oc5ccccc56)cc4-c4ccccc4)c3c2)cc1 ; CC(C)(C)c1ccc2c(c1)c1cc(C(C)(C)C)cc(C(C)(C)C)c1n2-c1c(-c2ccccc2)cc(-c2nc(-c3ccccc3)nc3c2oc2ccccc23)cc1-c1ccccc1]

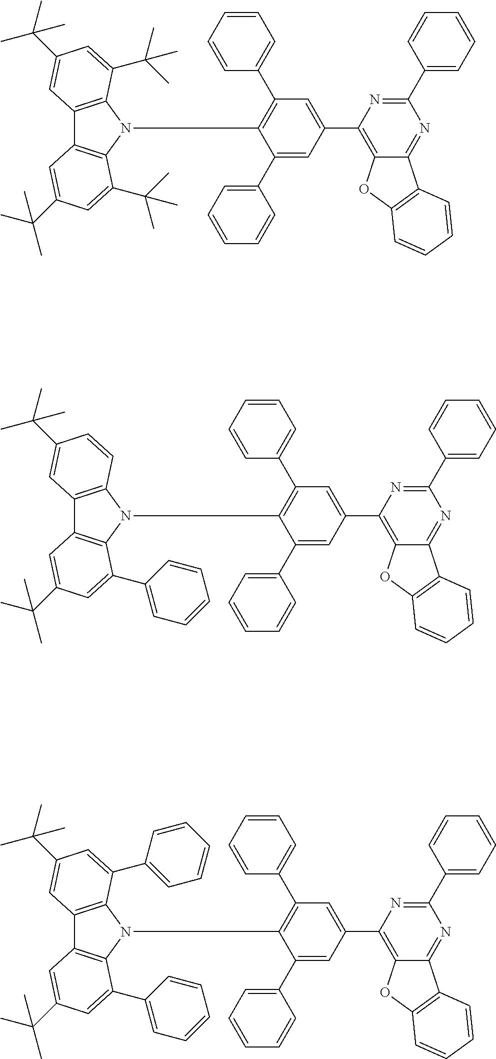 [SMILES: CC(C)(C)c1cc(C(C)(C)C)c2c(c1)c1cc(C(C)(C)C)cc(C(C)(C)C)c1n2-c1c(-c2ccccc2)cc(-c2nc(-c3ccccc3)nc3c2oc2ccccc23)cc1-c1ccccc1 ; CC(C)(C)c1ccc2c(c1)c1cc(C(C)(C)C)cc(-c3ccccc3)c1n2-c1c(-c2ccccc2)cc(-c2nc(-c3ccccc3)nc3c2oc2ccccc23)cc1-c1ccccc1 ; CC(C)(C)c1cc(-c2ccccc2)c2c(c1)c1cc(C(C)(C)C)cc(-c3ccccc3)c1n2-c1c(-c2ccccc2)cc(-c2nc(-c3ccccc3)nc3c2oc2ccccc23)cc1-c1ccccc1]

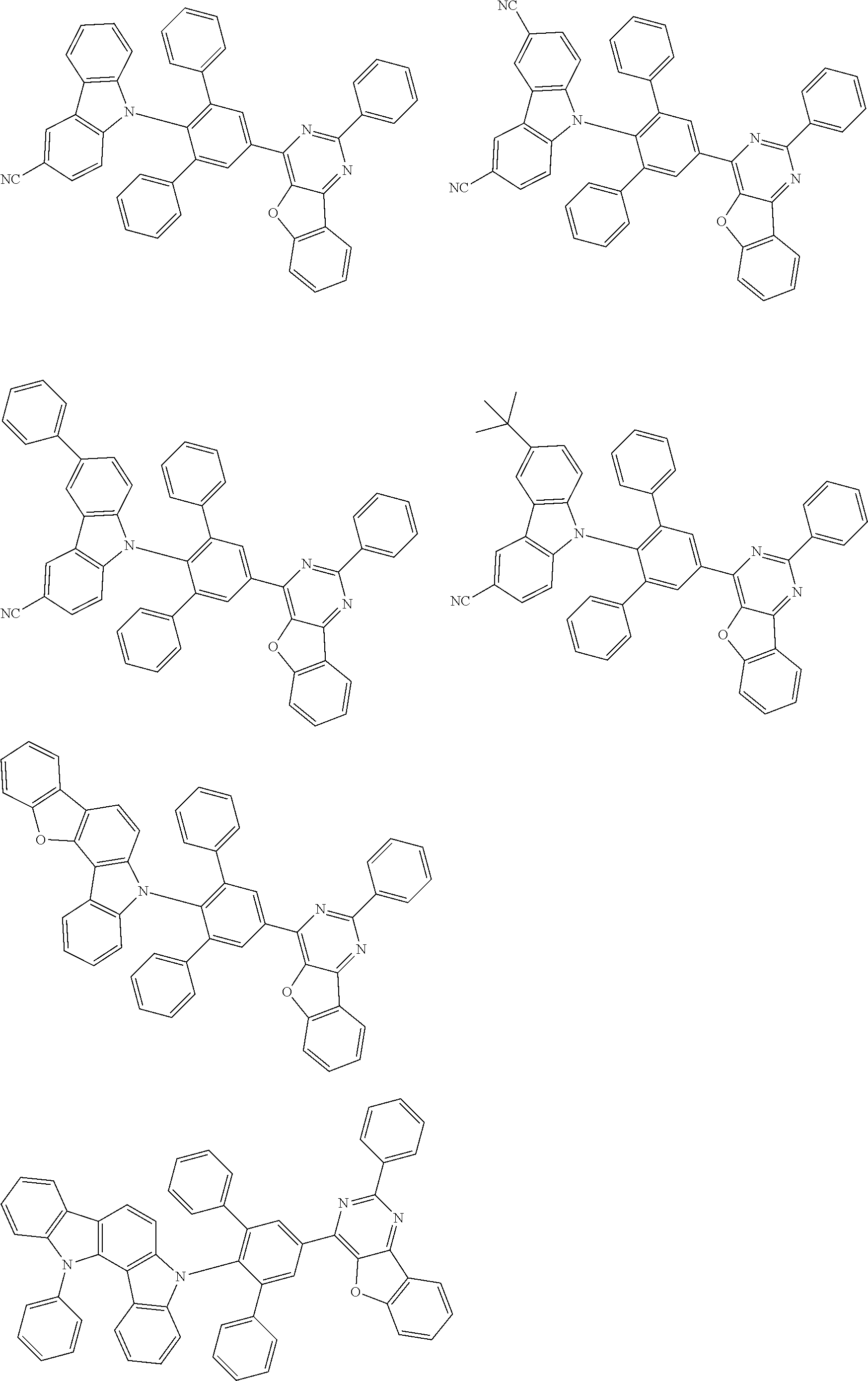

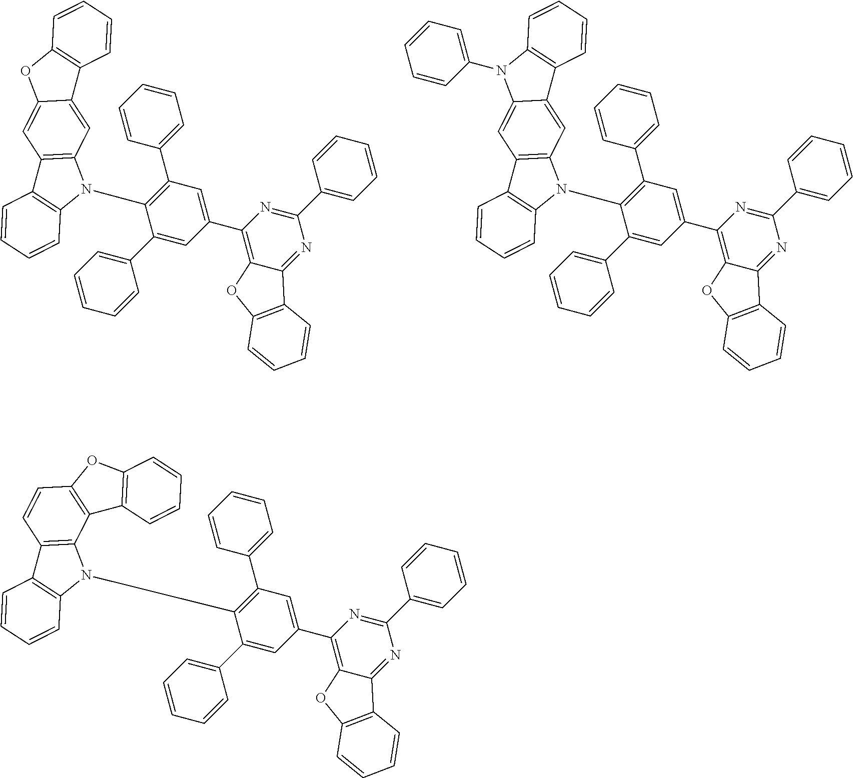 [SMILES: c1ccc(-c2nc(-c3cc(-c4ccccc4)c(-n4c5ccccc5c5cc6oc7ccccc7c6cc54)c(-c4ccccc4)c3)c3oc4ccccc4c3n2)cc1 ; c1ccc(-c2nc(-c3cc(-c4ccccc4)c(-n4c5ccccc5c5cc6c(cc54)c4ccccc4n6-c4ccccc4)c(-c4ccccc4)c3)c3oc4ccccc4c3n2)cc1 ; c1ccc(-c2nc(-c3cc(-c4ccccc4)c(-n4c5ccccc5c5ccc6oc7ccccc7c6c54)c(-c4ccccc4)c3)c3oc4ccccc4c3n2)cc1]

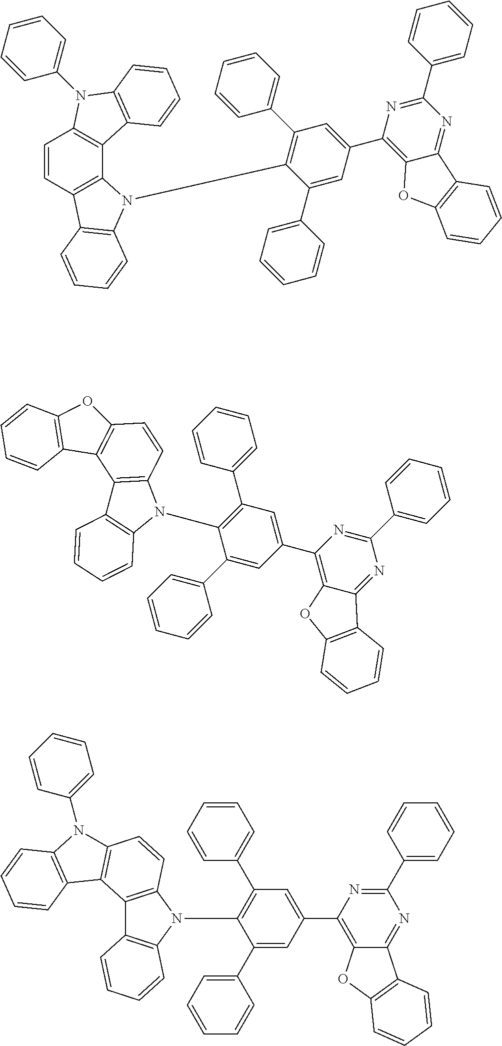 [SMILES: c1ccc(-c2nc(-c3cc(-c4ccccc4)c(-n4c5ccccc5c5ccc6c(c7ccccc7n6-c6ccccc6)c54)c(-c4ccccc4)c3)c3oc4ccccc4c3n2)cc1 ; c1ccc(-c2nc(-c3cc(-c4ccccc4)c(-n4c5ccccc5c5c6c(ccc54)oc4ccccc46)c(-c4ccccc4)c3)c3oc4ccccc4c3n2)cc1 ; c1ccc(-c2nc(-c3cc(-c4ccccc4)c(-n4c5ccccc5c5c6c7ccccc7n(-c7ccccc7)c6ccc54)c(-c4ccccc4)c3)c3oc4ccccc4c3n2)cc1]

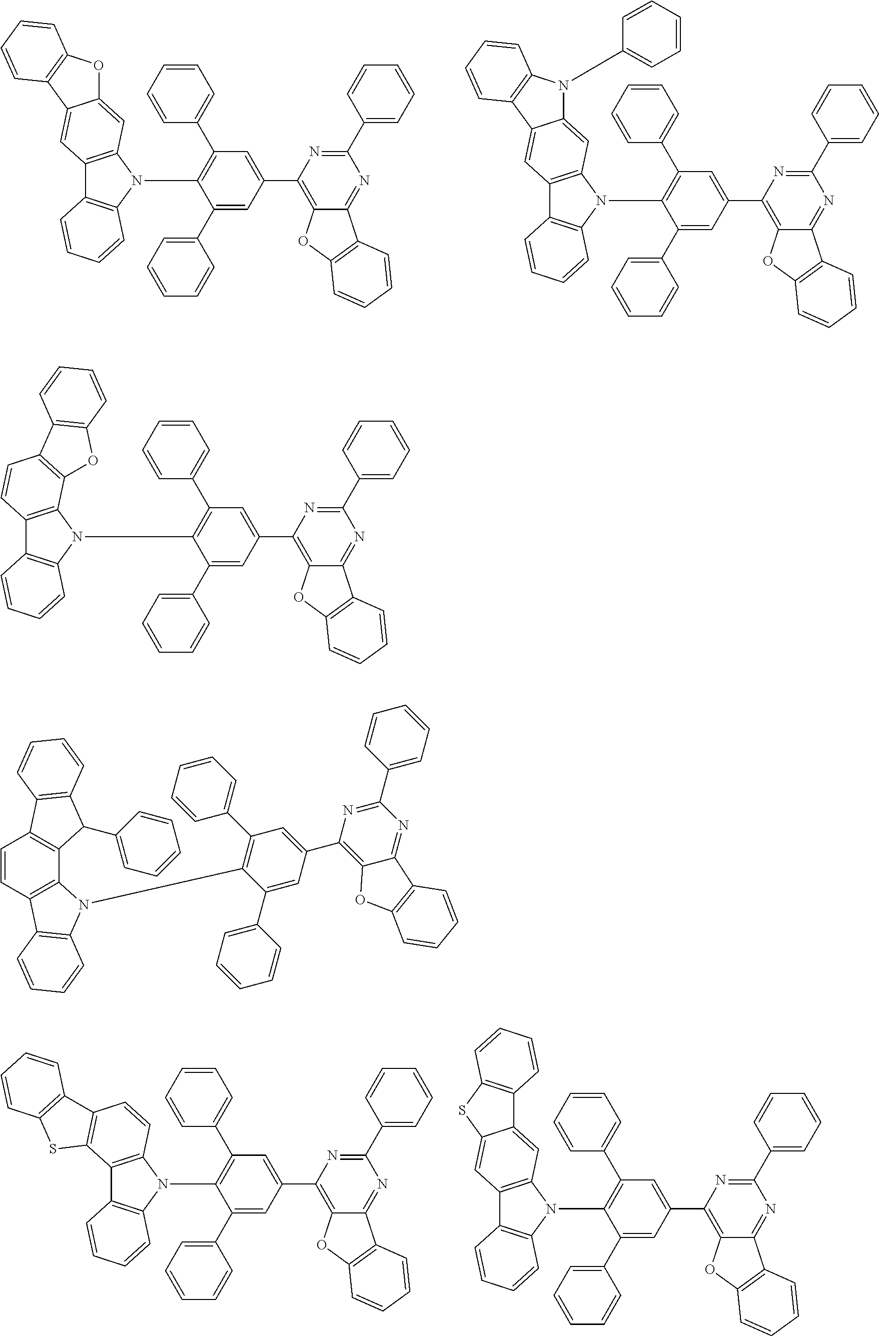

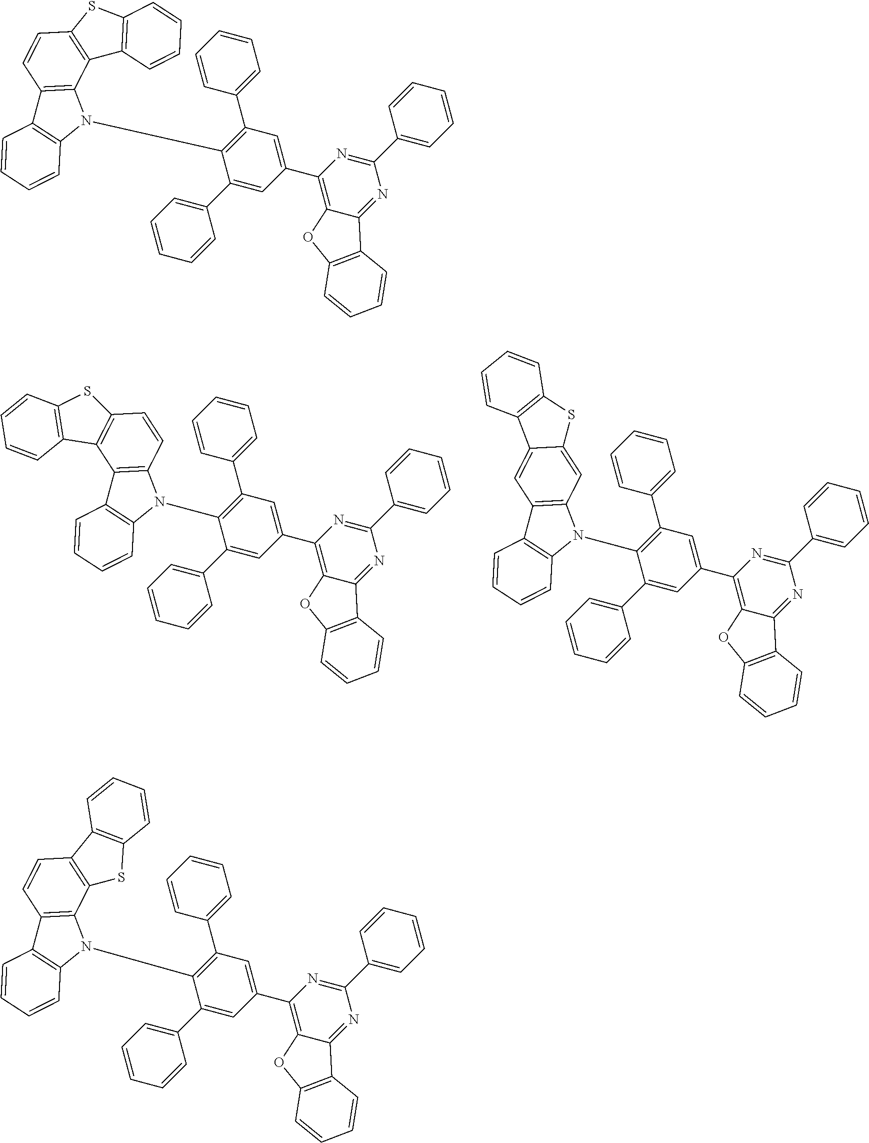 [SMILES: c1ccc(-c2nc(-c3cc(-c4ccccc4)c(-n4c5ccccc5c5ccc6sc7ccccc7c6c54)c(-c4ccccc4)c3)c3oc4ccccc4c3n2)cc1 ; c1ccc(-c2nc(-c3cc(-c4ccccc4)c(-n4c5ccccc5c5c6c(ccc54)sc4ccccc46)c(-c4ccccc4)c3)c3oc4ccccc4c3n2)cc1 ; c1ccc(-c2nc(-c3cc(-c4ccccc4)c(-n4c5ccccc5c5cc6c(cc54)sc4ccccc46)c(-c4ccccc4)c3)c3oc4ccccc4c3n2)cc1 ; c1ccc(-c2nc(-c3cc(-c4ccccc4)c(-n4c5ccccc5c5ccc6c7ccccc7sc6c54)c(-c4ccccc4)c3)c3oc4ccccc4c3n2)cc1]

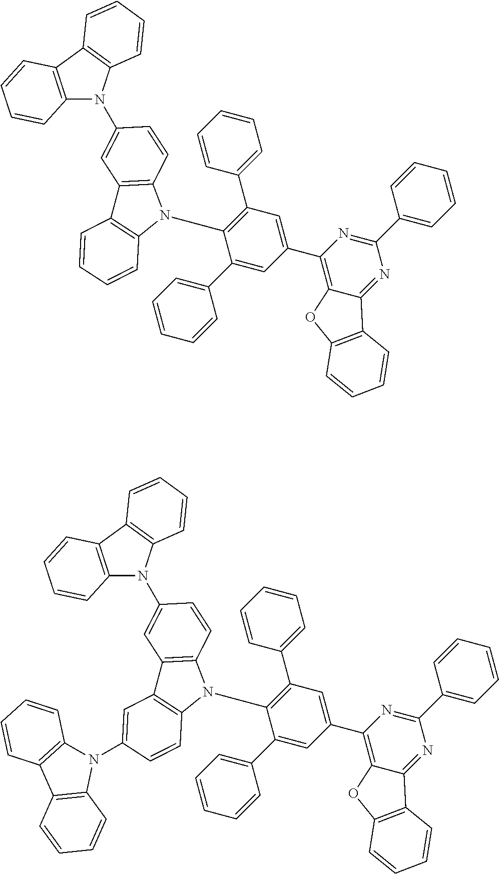 [SMILES: c1ccc(-c2nc(-c3cc(-c4ccccc4)c(-n4c5ccccc5c5cc(-n6c7ccccc7c7ccccc76)ccc54)c(-c4ccccc4)c3)c3oc4ccccc4c3n2)cc1 ; c1ccc(-c2nc(-c3cc(-c4ccccc4)c(-n4c5ccc(-n6c7ccccc7c7ccccc76)cc5c5cc(-n6c7ccccc7c7ccccc76)ccc54)c(-c4ccccc4)c3)c3oc4ccccc4c3n2)cc1]

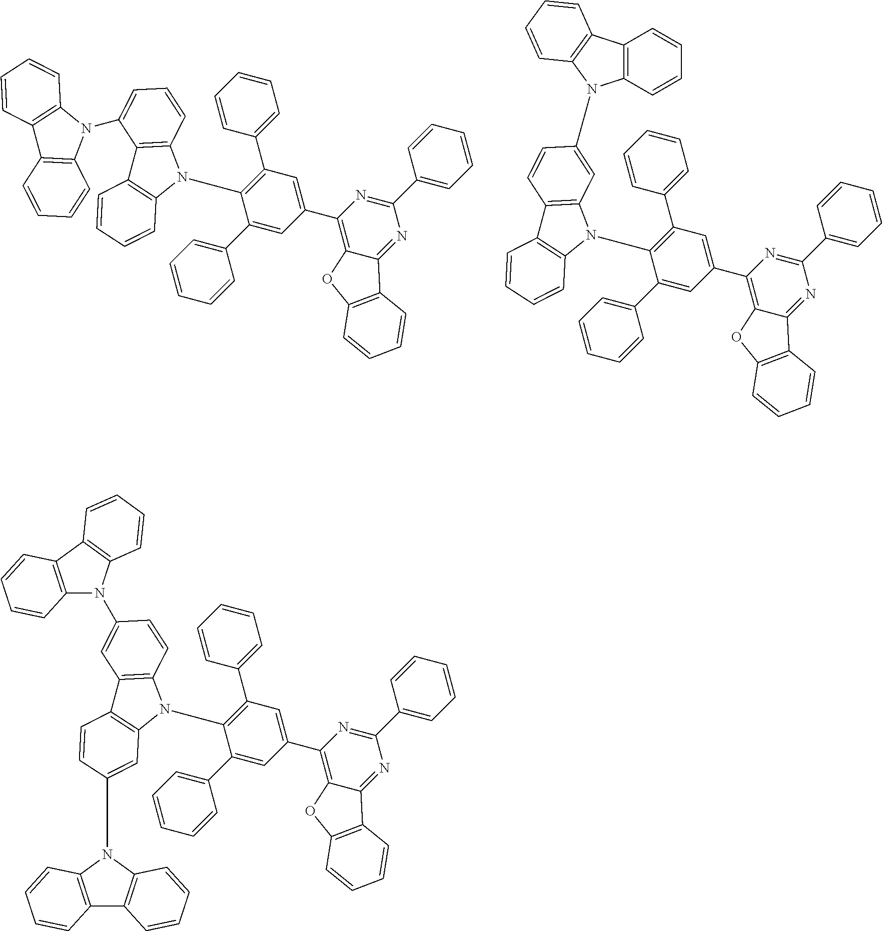 [SMILES: c1ccc(-c2nc(-c3cc(-c4ccccc4)c(-n4c5ccccc5c5c(-n6c7ccccc7c7ccccc76)cccc54)c(-c4ccccc4)c3)c3oc4ccccc4c3n2)cc1 ; c1ccc(-c2nc(-c3cc(-c4ccccc4)c(-n4c5ccccc5c5ccc(-n6c7ccccc7c7ccccc76)cc54)c(-c4ccccc4)c3)c3oc4ccccc4c3n2)cc1 ; c1ccc(-c2nc(-c3cc(-c4ccccc4)c(-n4c5ccc(-n6c7ccccc7c7ccccc76)cc5c5ccc(-n6c7ccccc7c7ccccc76)cc54)c(-c4ccccc4)c3)c3oc4ccccc4c3n2)cc1]

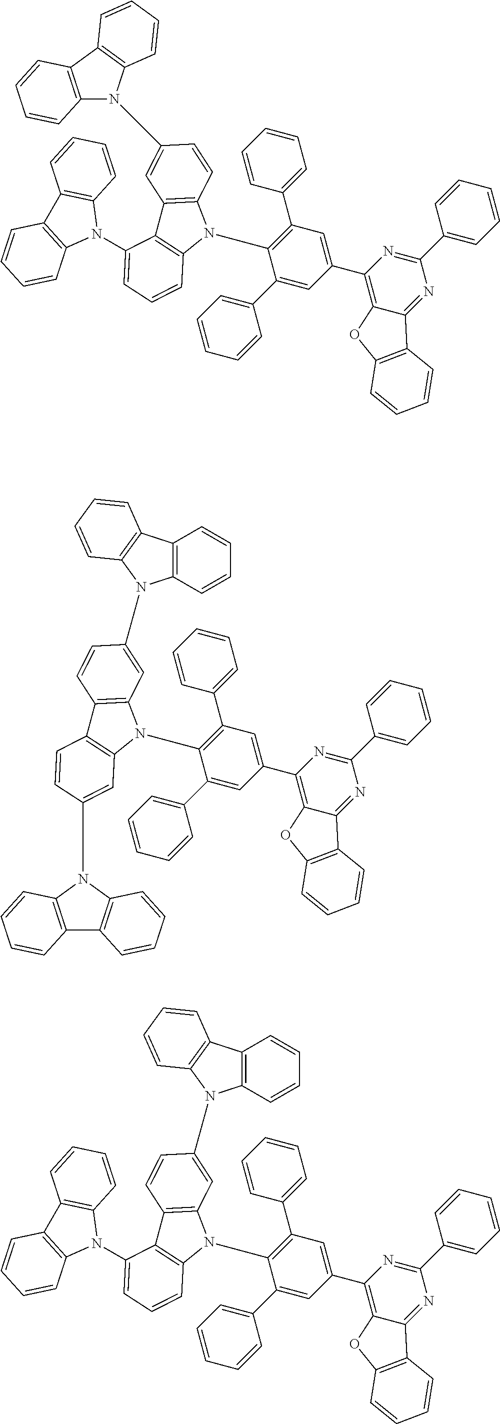 [SMILES: c1ccc(-c2nc(-c3cc(-c4ccccc4)c(-n4c5ccc(-n6c7ccccc7c7ccccc76)cc5c5c(-n6c7ccccc7c7ccccc76)cccc54)c(-c4ccccc4)c3)c3oc4ccccc4c3n2)cc1 ; c1ccc(-c2nc(-c3cc(-c4ccccc4)c(-n4c5cc(-n6c7ccccc7c7ccccc76)ccc5c5ccc(-n6c7ccccc7c7ccccc76)cc54)c(-c4ccccc4)c3)c3oc4ccccc4c3n2)cc1 ; c1ccc(-c2nc(-c3cc(-c4ccccc4)c(-n4c5cc(-n6c7ccccc7c7ccccc76)ccc5c5c(-n6c7ccccc7c7ccccc76)cccc54)c(-c4ccccc4)c3)c3oc4ccccc4c3n2)cc1]

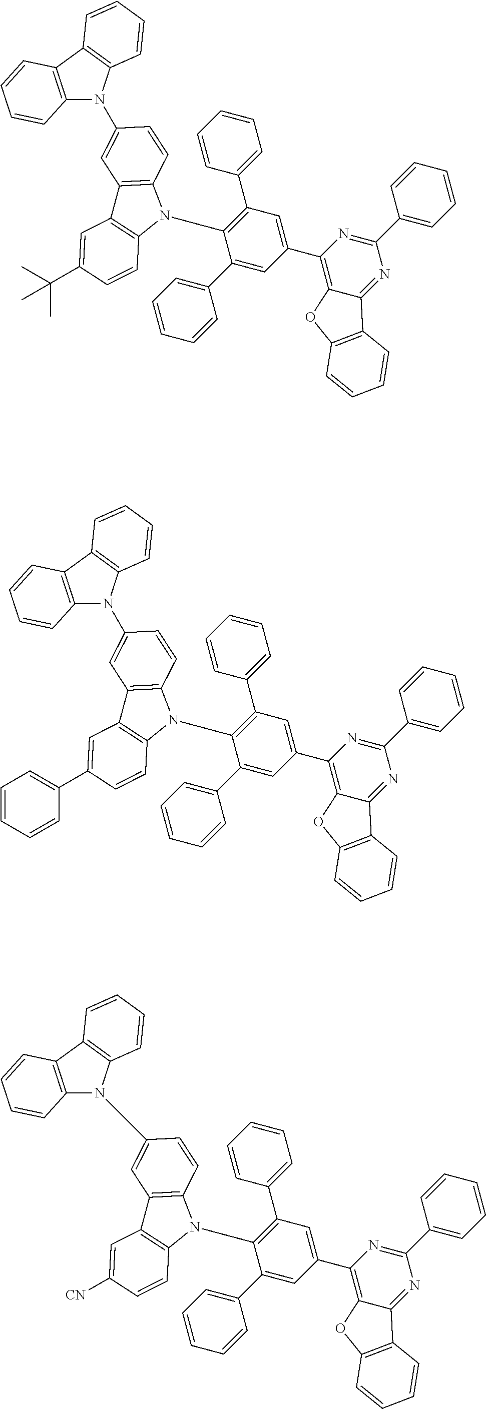

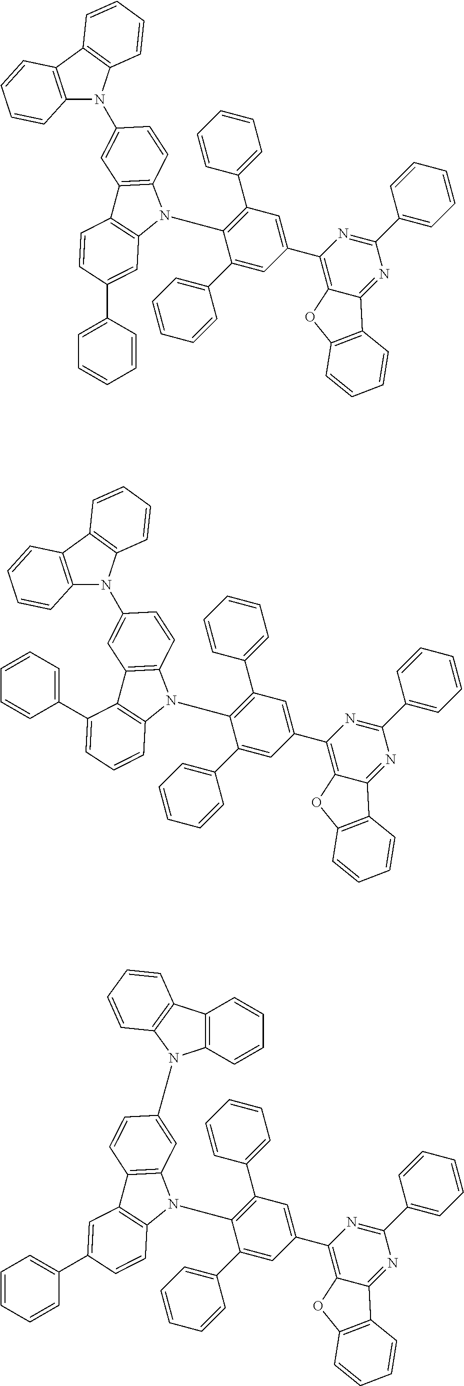 [SMILES: c1ccc(-c2ccc3c4cc(-n5c6ccccc6c6ccccc65)ccc4n(-c4c(-c5ccccc5)cc(-c5nc(-c6ccccc6)nc6c5oc5ccccc56)cc4-c4ccccc4)c3c2)cc1 ; c1ccc(-c2nc(-c3cc(-c4ccccc4)c(-n4c5ccc(-n6c7ccccc7c7ccccc76)cc5c5c(-c6ccccc6)cccc54)c(-c4ccccc4)c3)c3oc4ccccc4c3n2)cc1 ; c1ccc(-c2ccc3c(c2)c2ccc(-n4c5ccccc5c5ccccc54)cc2n3-c2c(-c3ccccc3)cc(-c3nc(-c4ccccc4)nc4c3oc3ccccc34)cc2-c2ccccc2)cc1]

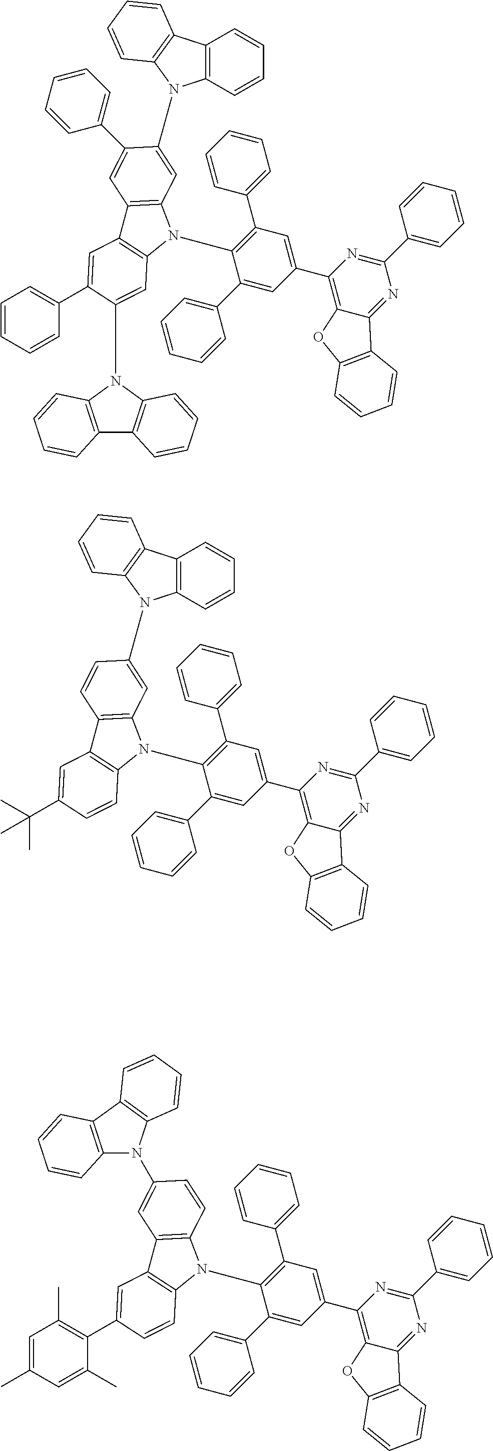 [SMILES: c1ccc(-c2nc(-c3cc(-c4ccccc4)c(-n4c5cc(-n6c7ccccc7c7ccccc76)c(-c6ccccc6)cc5c5cc(-c6ccccc6)c(-n6c7ccccc7c7ccccc76)cc54)c(-c4ccccc4)c3)c3oc4ccccc4c3n2)cc1 ; CC(C)(C)c1ccc2c(c1)c1ccc(-n3c4ccccc4c4ccccc43)cc1n2-c1c(-c2ccccc2)cc(-c2nc(-c3ccccc3)nc3c2oc2ccccc23)cc1-c1ccccc1 ; Cc1cc(C)c(-c2ccc3c(c2)c2cc(-n4c5ccccc5c5ccccc54)ccc2n3-c2c(-c3ccccc3)cc(-c3nc(-c4ccccc4)nc4c3oc3ccccc34)cc2-c2ccccc2)c(C)c1]

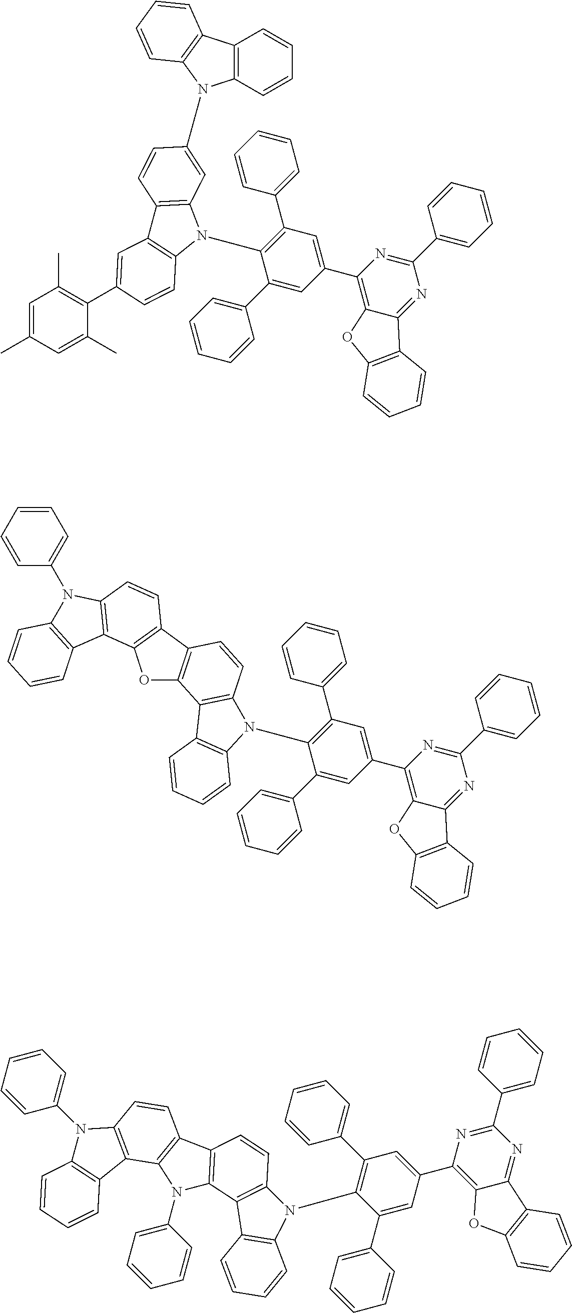 [SMILES: Cc1cc(C)c(-c2ccc3c(c2)c2ccc(-n4c5ccccc5c5ccccc54)cc2n3-c2c(-c3ccccc3)cc(-c3nc(-c4ccccc4)nc4c3oc3ccccc34)cc2-c2ccccc2)c(C)c1 ; c1ccc(-c2nc(-c3cc(-c4ccccc4)c(-n4c5ccccc5c5c6oc7c(ccc8c7c7ccccc7n8-c7ccccc7)c6ccc54)c(-c4ccccc4)c3)c3oc4ccccc4c3n2)cc1 ; c1ccc(-c2nc(-c3cc(-c4ccccc4)c(-n4c5ccccc5c5c4ccc4c6ccc7c(c8ccccc8n7-c7ccccc7)c6n(-c6ccccc6)c45)c(-c4ccccc4)c3)c3oc4ccccc4c3n2)cc1]

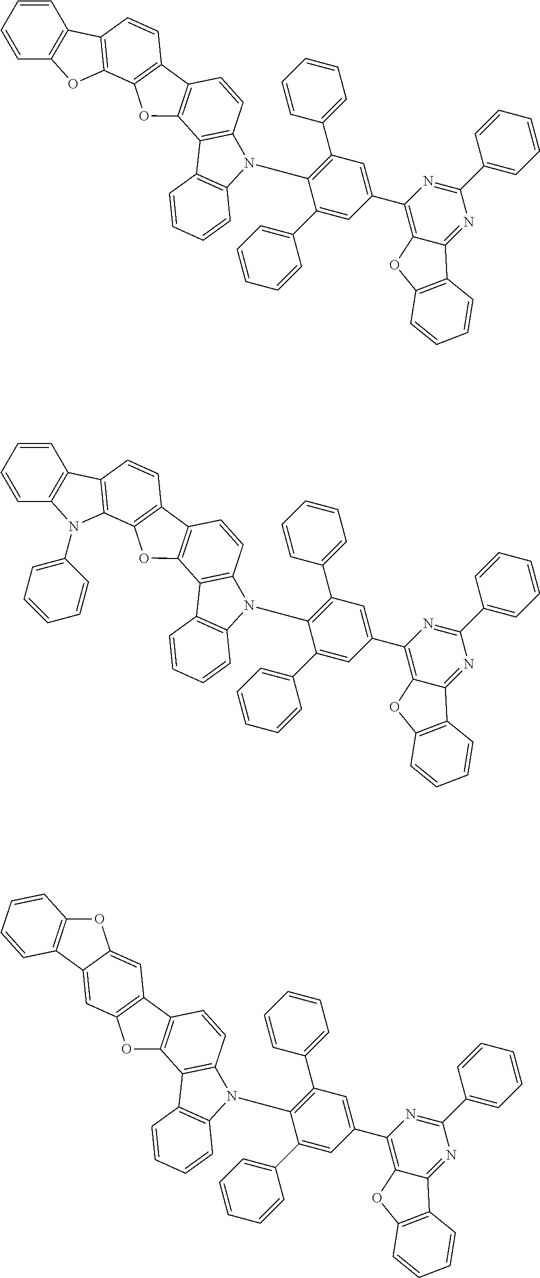 [SMILES: c1ccc(-c2nc(-c3cc(-c4ccccc4)c(-n4c5ccccc5c5c6oc7c(ccc8c9ccccc9oc87)c6ccc54)c(-c4ccccc4)c3)c3oc4ccccc4c3n2)cc1 ; c1ccc(-c2nc(-c3cc(-c4ccccc4)c(-n4c5ccccc5c5c6oc7c(ccc8c9ccccc9n(-c9ccccc9)c87)c6ccc54)c(-c4ccccc4)c3)c3oc4ccccc4c3n2)cc1 ; c1ccc(-c2nc(-c3cc(-c4ccccc4)c(-n4c5ccccc5c5c6oc7cc8c(cc7c6ccc54)oc4ccccc48)c(-c4ccccc4)c3)c3oc4ccccc4c3n2)cc1]

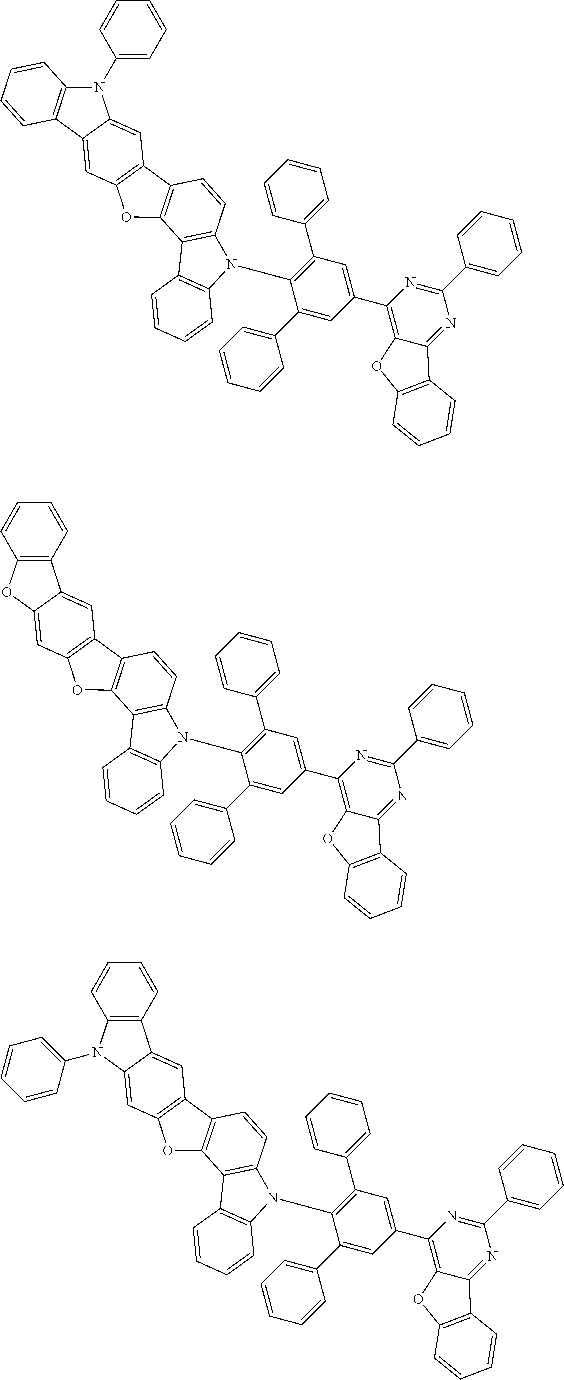 [SMILES: c1ccc(-c2nc(-c3cc(-c4ccccc4)c(-n4c5ccccc5c5c6oc7cc8c9ccccc9n(-c9ccccc9)c8cc7c6ccc54)c(-c4ccccc4)c3)c3oc4ccccc4c3n2)cc1 ; c1ccc(-c2nc(-c3cc(-c4ccccc4)c(-n4c5ccccc5c5c6oc7cc8oc9ccccc9c8cc7c6ccc54)c(-c4ccccc4)c3)c3oc4ccccc4c3n2)cc1 ; c1ccc(-c2nc(-c3cc(-c4ccccc4)c(-n4c5ccccc5c5c6oc7cc8c(cc7c6ccc54)c4ccccc4n8-c4ccccc4)c(-c4ccccc4)c3)c3oc4ccccc4c3n2)cc1]

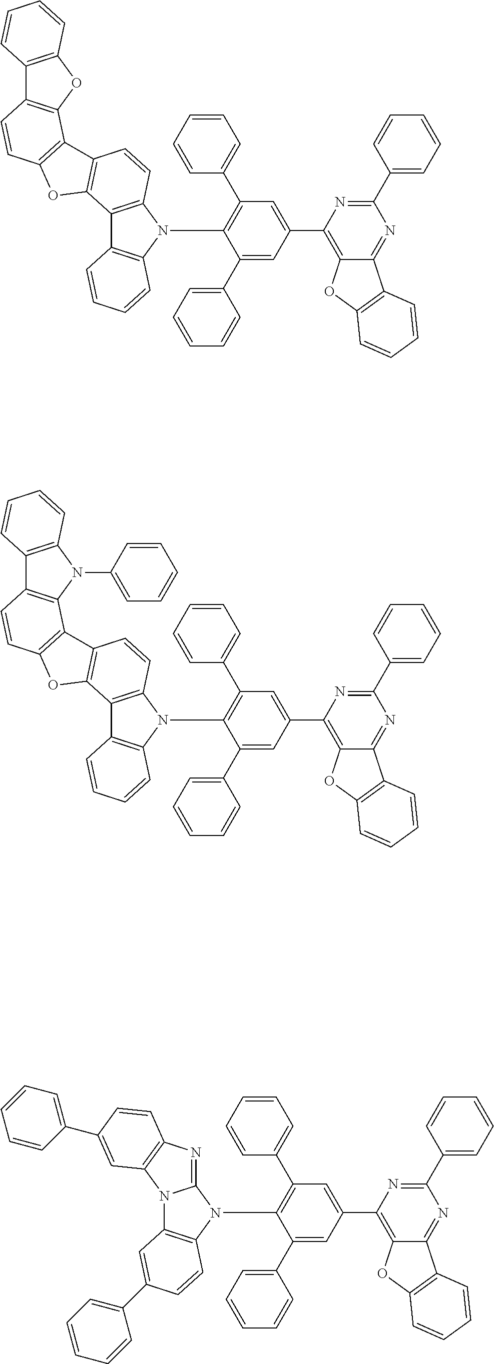 [SMILES: c1ccc(-c2nc(-c3cc(-c4ccccc4)c(-n4c5ccccc5c5c6oc7ccc8c9ccccc9oc8c7c6ccc54)c(-c4ccccc4)c3)c3oc4ccccc4c3n2)cc1 ; c1ccc(-c2nc(-c3cc(-c4ccccc4)c(-n4c5ccccc5c5c6oc7ccc8c9ccccc9n(-c9ccccc9)c8c7c6ccc54)c(-c4ccccc4)c3)c3oc4ccccc4c3n2)cc1 ; c1ccc(-c2ccc3nc4n(-c5c(-c6ccccc6)cc(-c6nc(-c7ccccc7)nc7c6oc6ccccc67)cc5-c5ccccc5)c5ccc(-c6ccccc6)cc5n4c3c2)cc1]

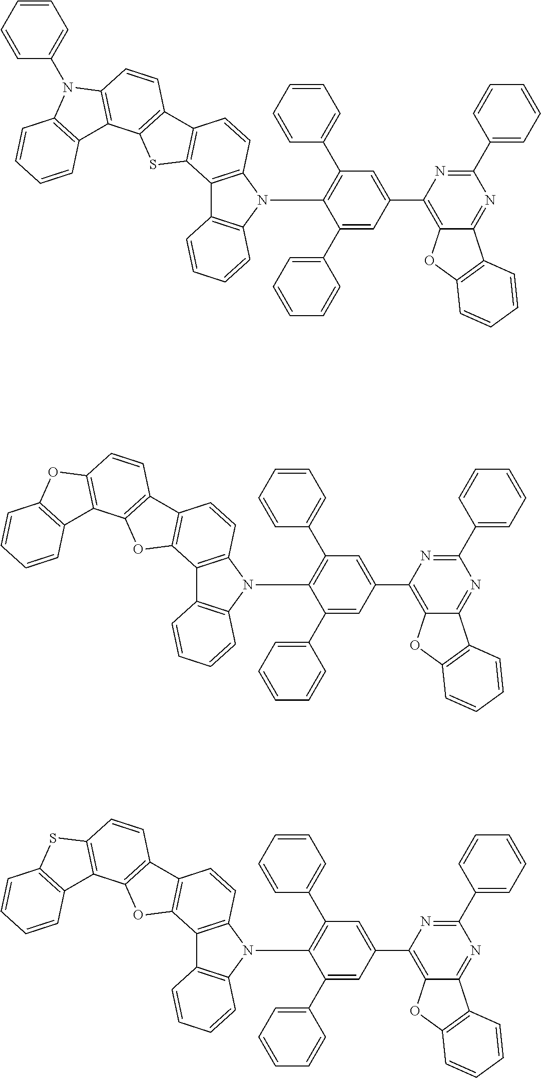 [SMILES: c1ccc(-c2nc(-c3cc(-c4ccccc4)c(-n4c5ccccc5c5c6sc7c(ccc8c7c7ccccc7n8-c7ccccc7)c6ccc54)c(-c4ccccc4)c3)c3oc4ccccc4c3n2)cc1 ; c1ccc(-c2nc(-c3cc(-c4ccccc4)c(-n4c5ccccc5c5c6oc7c(ccc8oc9ccccc9c87)c6ccc54)c(-c4ccccc4)c3)c3oc4ccccc4c3n2)cc1 ; c1ccc(-c2nc(-c3cc(-c4ccccc4)c(-n4c5ccccc5c5c6oc7c(ccc8sc9ccccc9c87)c6ccc54)c(-c4ccccc4)c3)c3oc4ccccc4c3n2)cc1]

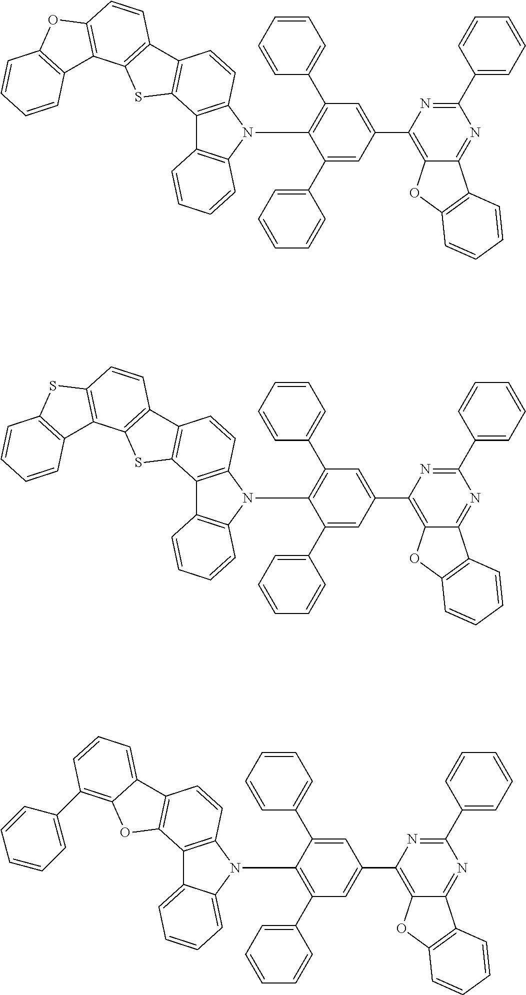 [SMILES: c1ccc(-c2nc(-c3cc(-c4ccccc4)c(-n4c5ccccc5c5c6sc7c(ccc8oc9ccccc9c87)c6ccc54)c(-c4ccccc4)c3)c3oc4ccccc4c3n2)cc1 ; c1ccc(-c2nc(-c3cc(-c4ccccc4)c(-n4c5ccccc5c5c6sc7c(ccc8sc9ccccc9c87)c6ccc54)c(-c4ccccc4)c3)c3oc4ccccc4c3n2)cc1 ; c1ccc(-c2nc(-c3cc(-c4ccccc4)c(-n4c5ccccc5c5c6oc7c(-c8ccccc8)cccc7c6ccc54)c(-c4ccccc4)c3)c3oc4ccccc4c3n2)cc1]

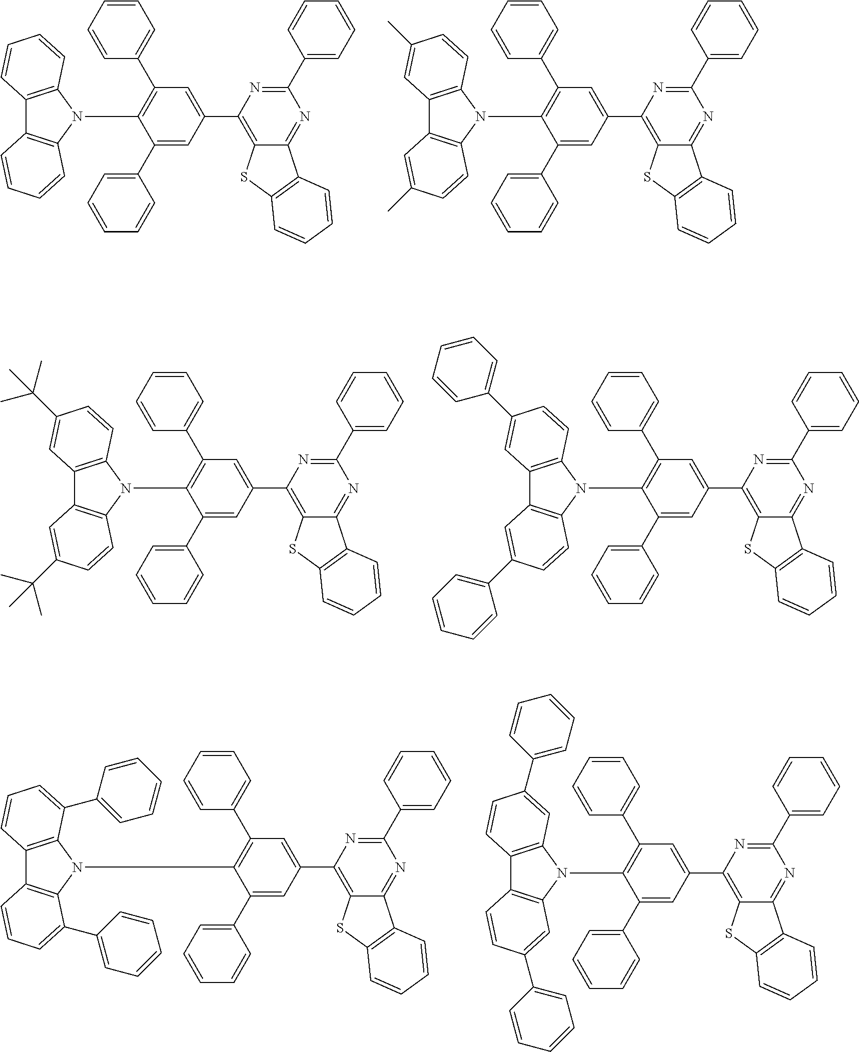

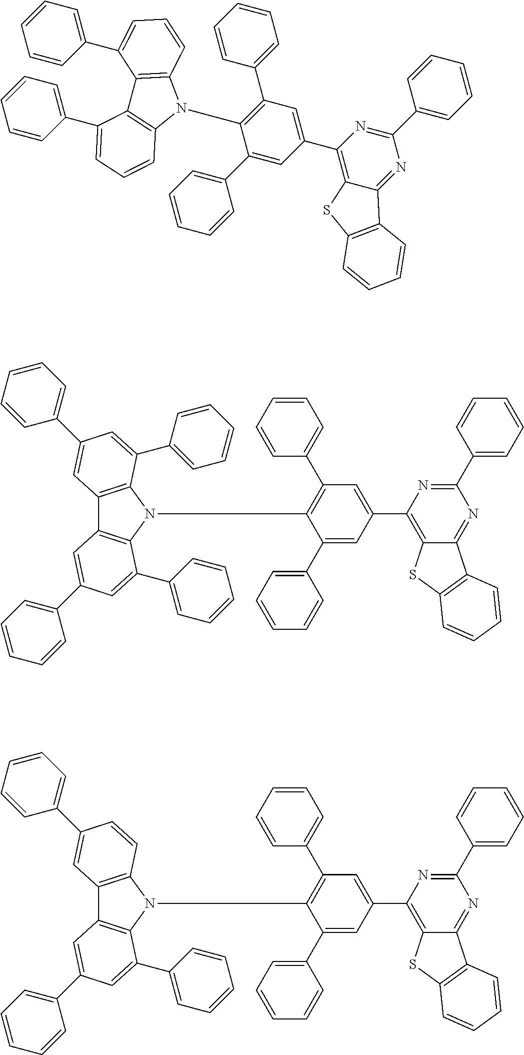 [SMILES: c1ccc(-c2nc(-c3cc(-c4ccccc4)c(-n4c5cccc(-c6ccccc6)c5c5c(-c6ccccc6)cccc54)c(-c4ccccc4)c3)c3sc4ccccc4c3n2)cc1 ; c1ccc(-c2cc(-c3ccccc3)c3c(c2)c2cc(-c4ccccc4)cc(-c4ccccc4)c2n3-c2c(-c3ccccc3)cc(-c3nc(-c4ccccc4)nc4c3sc3ccccc34)cc2-c2ccccc2)cc1 ; c1ccc(-c2ccc3c(c2)c2cc(-c4ccccc4)cc(-c4ccccc4)c2n3-c2c(-c3ccccc3)cc(-c3nc(-c4ccccc4)nc4c3sc3ccccc34)cc2-c2ccccc2)cc1]

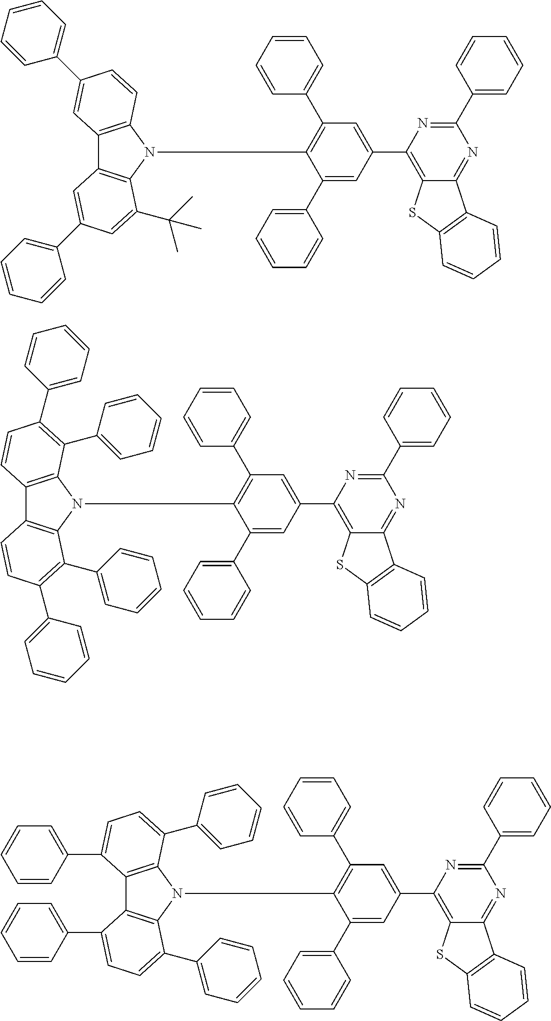

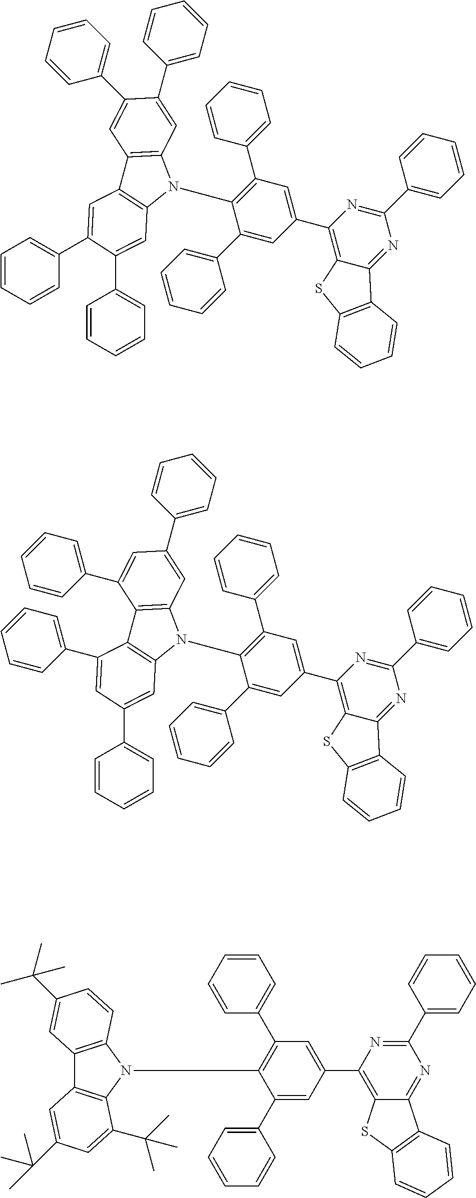 [SMILES: c1ccc(-c2nc(-c3cc(-c4ccccc4)c(-n4c5cc(-c6ccccc6)c(-c6ccccc6)cc5c5cc(-c6ccccc6)c(-c6ccccc6)cc54)c(-c4ccccc4)c3)c3sc4ccccc4c3n2)cc1 ; c1ccc(-c2cc(-c3ccccc3)c3c4c(-c5ccccc5)cc(-c5ccccc5)cc4n(-c4c(-c5ccccc5)cc(-c5nc(-c6ccccc6)nc6c5sc5ccccc56)cc4-c4ccccc4)c3c2)cc1 ; CC(C)(C)c1ccc2c(c1)c1cc(C(C)(C)C)cc(C(C)(C)C)c1n2-c1c(-c2ccccc2)cc(-c2nc(-c3ccccc3)nc3c2sc2ccccc23)cc1-c1ccccc1]

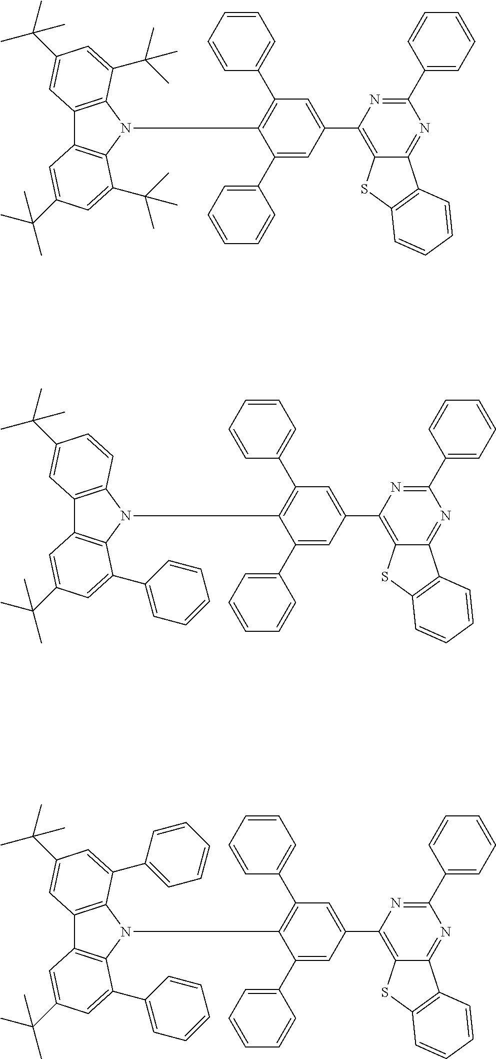 [SMILES: CC(C)(C)c1cc(C(C)(C)C)c2c(c1)c1cc(C(C)(C)C)cc(C(C)(C)C)c1n2-c1c(-c2ccccc2)cc(-c2nc(-c3ccccc3)nc3c2sc2ccccc23)cc1-c1ccccc1 ; CC(C)(C)c1ccc2c(c1)c1cc(C(C)(C)C)cc(-c3ccccc3)c1n2-c1c(-c2ccccc2)cc(-c2nc(-c3ccccc3)nc3c2sc2ccccc23)cc1-c1ccccc1 ; CC(C)(C)c1cc(-c2ccccc2)c2c(c1)c1cc(C(C)(C)C)cc(-c3ccccc3)c1n2-c1c(-c2ccccc2)cc(-c2nc(-c3ccccc3)nc3c2sc2ccccc23)cc1-c1ccccc1]

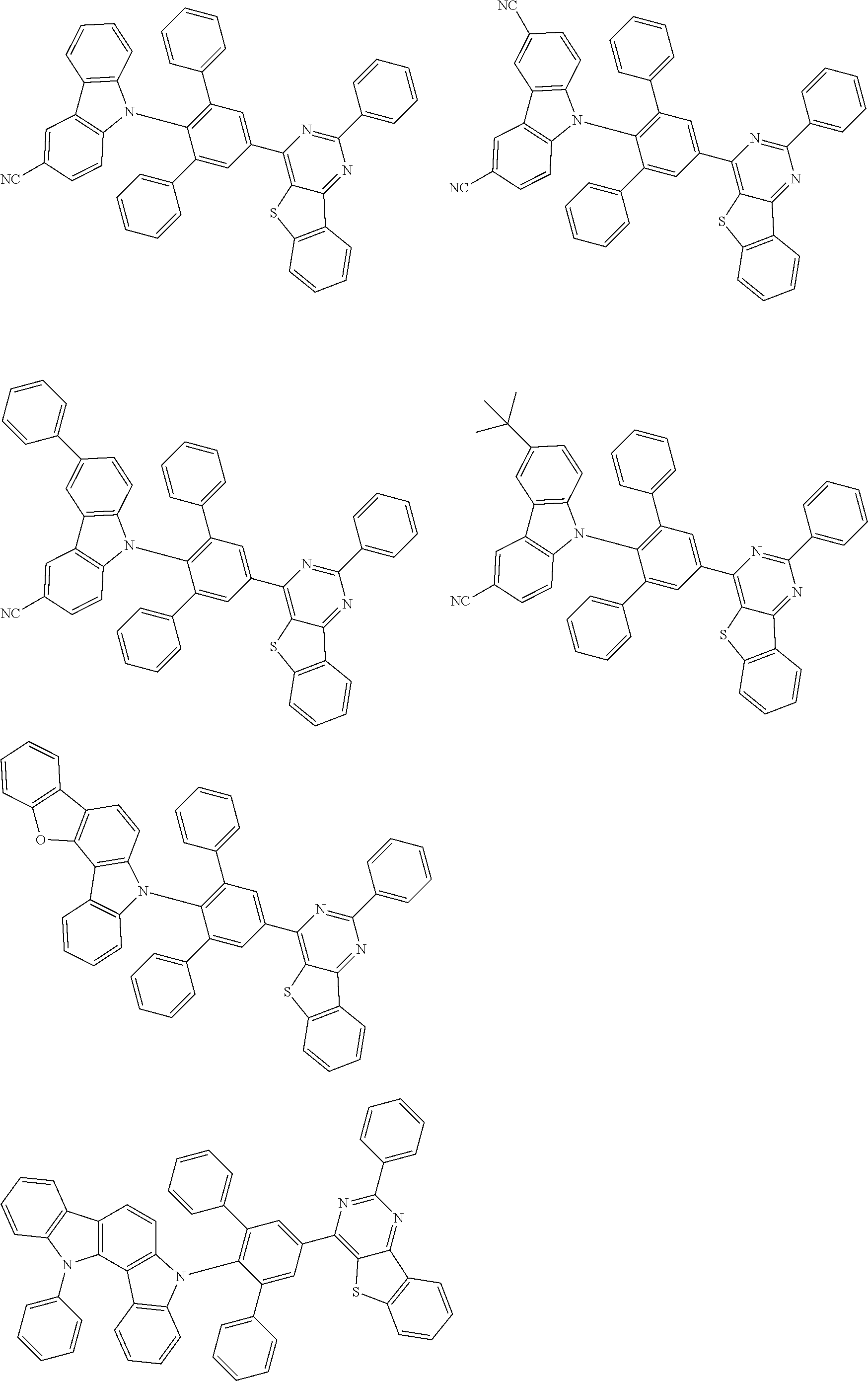

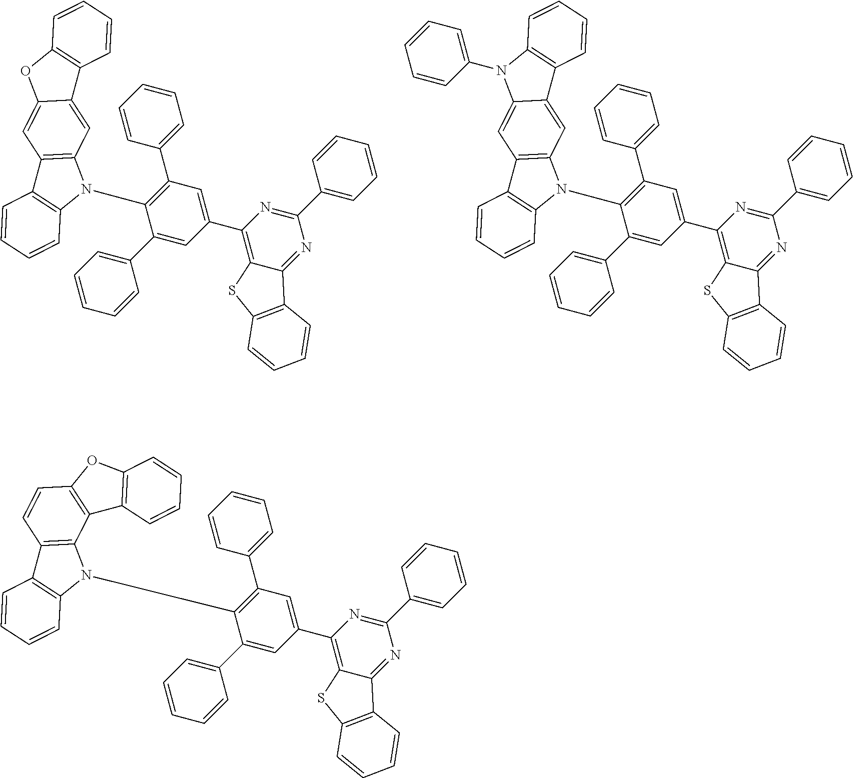 [SMILES: c1ccc(-c2nc(-c3cc(-c4ccccc4)c(-n4c5ccccc5c5cc6oc7ccccc7c6cc54)c(-c4ccccc4)c3)c3sc4ccccc4c3n2)cc1 ; c1ccc(-c2nc(-c3cc(-c4ccccc4)c(-n4c5ccccc5c5cc6c(cc54)c4ccccc4n6-c4ccccc4)c(-c4ccccc4)c3)c3sc4ccccc4c3n2)cc1 ; c1ccc(-c2nc(-c3cc(-c4ccccc4)c(-n4c5ccccc5c5ccc6oc7ccccc7c6c54)c(-c4ccccc4)c3)c3sc4ccccc4c3n2)cc1]

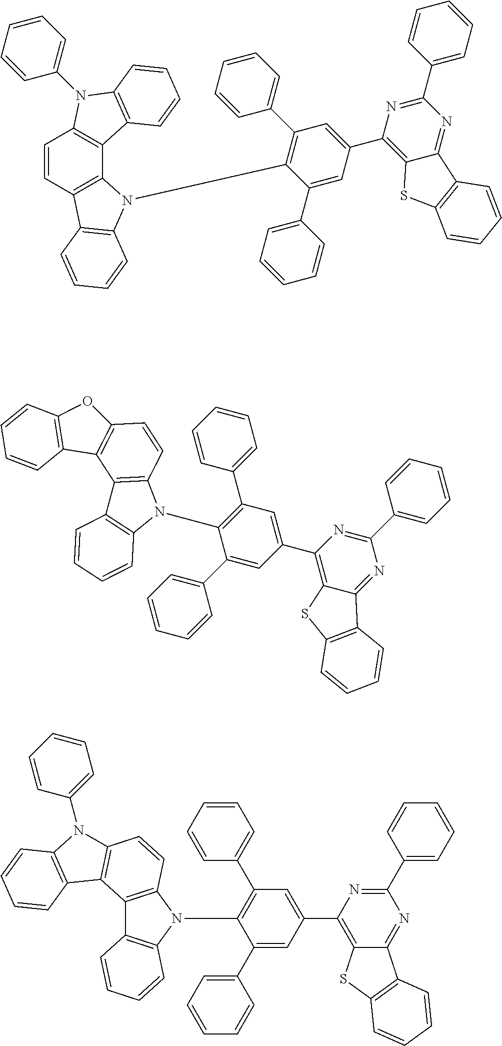 [SMILES: c1ccc(-c2nc(-c3cc(-c4ccccc4)c(-n4c5ccccc5c5ccc6c(c7ccccc7n6-c6ccccc6)c54)c(-c4ccccc4)c3)c3sc4ccccc4c3n2)cc1 ; c1ccc(-c2nc(-c3cc(-c4ccccc4)c(-n4c5ccccc5c5c6c(ccc54)oc4ccccc46)c(-c4ccccc4)c3)c3sc4ccccc4c3n2)cc1 ; c1ccc(-c2nc(-c3cc(-c4ccccc4)c(-n4c5ccccc5c5c6c7ccccc7n(-c7ccccc7)c6ccc54)c(-c4ccccc4)c3)c3sc4ccccc4c3n2)cc1]

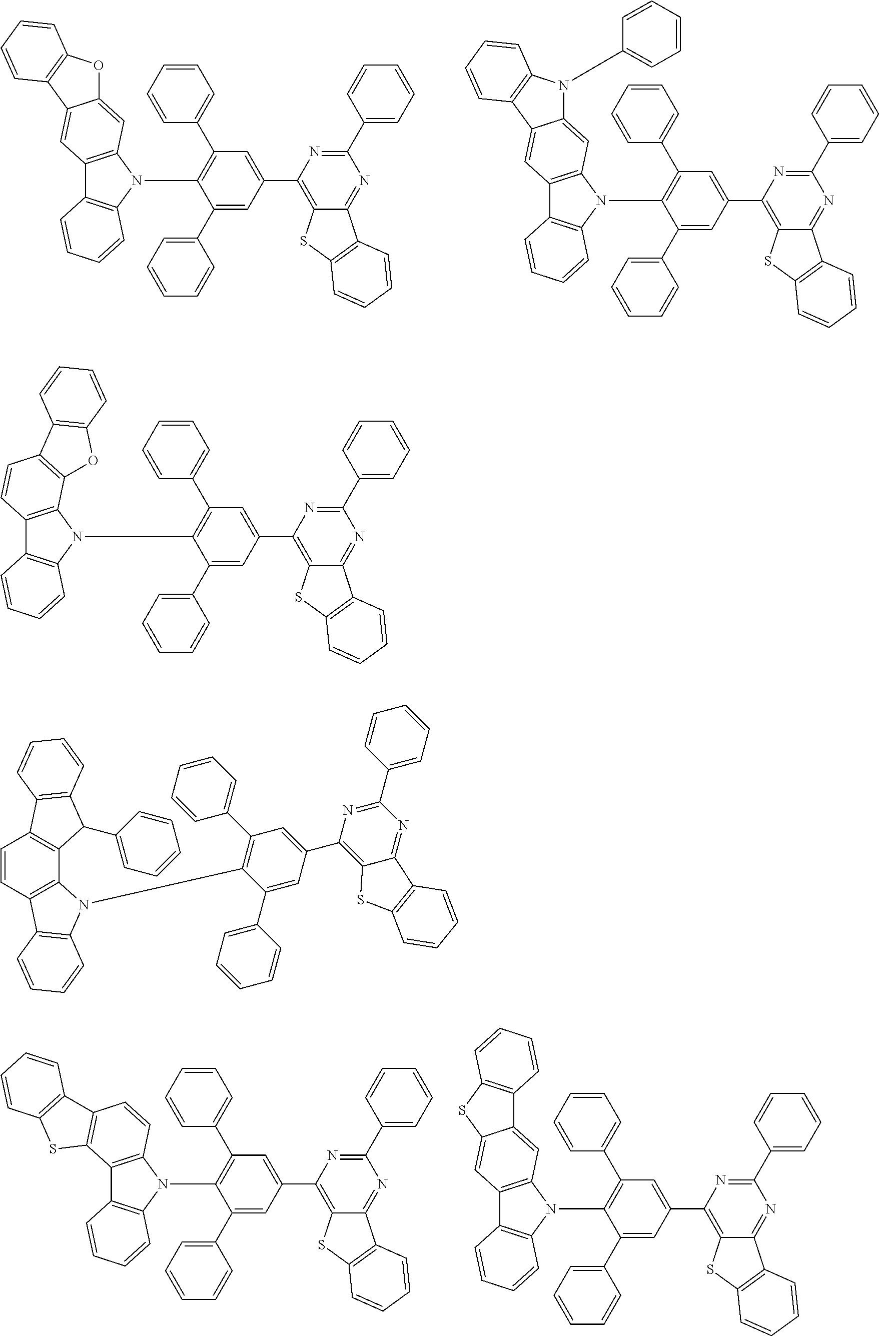

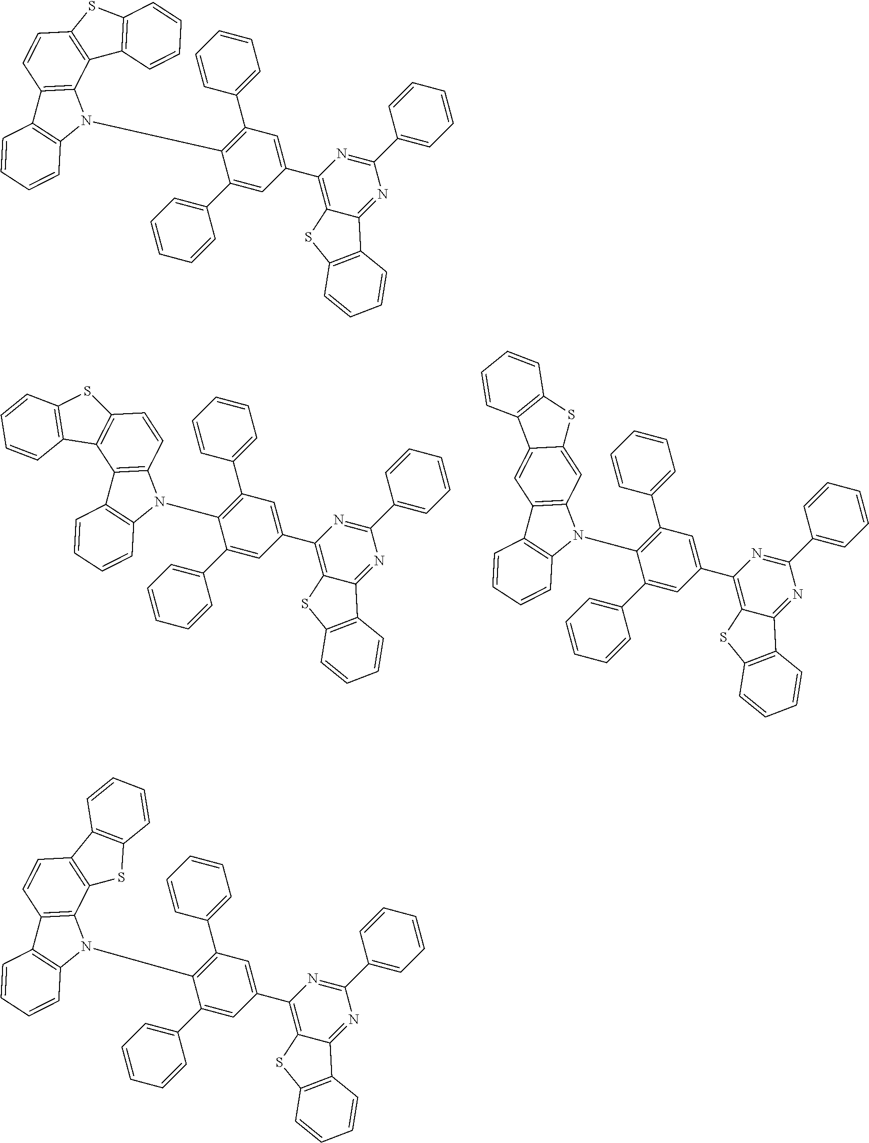 [SMILES: c1ccc(-c2nc(-c3cc(-c4ccccc4)c(-n4c5ccccc5c5ccc6sc7ccccc7c6c54)c(-c4ccccc4)c3)c3sc4ccccc4c3n2)cc1 ; c1ccc(-c2nc(-c3cc(-c4ccccc4)c(-n4c5ccccc5c5c6c(ccc54)sc4ccccc46)c(-c4ccccc4)c3)c3sc4ccccc4c3n2)cc1 ; c1ccc(-c2nc(-c3cc(-c4ccccc4)c(-n4c5ccccc5c5cc6c(cc54)sc4ccccc46)c(-c4ccccc4)c3)c3sc4ccccc4c3n2)cc1 ; c1ccc(-c2nc(-c3cc(-c4ccccc4)c(-n4c5ccccc5c5ccc6c7ccccc7sc6c54)c(-c4ccccc4)c3)c3sc4ccccc4c3n2)cc1]

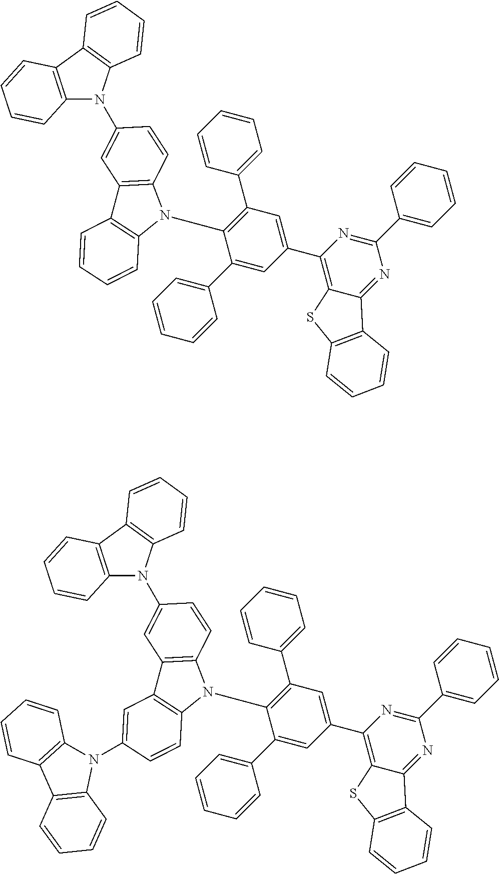 [SMILES: c1ccc(-c2nc(-c3cc(-c4ccccc4)c(-n4c5ccccc5c5cc(-n6c7ccccc7c7ccccc76)ccc54)c(-c4ccccc4)c3)c3sc4ccccc4c3n2)cc1 ; c1ccc(-c2nc(-c3cc(-c4ccccc4)c(-n4c5ccc(-n6c7ccccc7c7ccccc76)cc5c5cc(-n6c7ccccc7c7ccccc76)ccc54)c(-c4ccccc4)c3)c3sc4ccccc4c3n2)cc1]

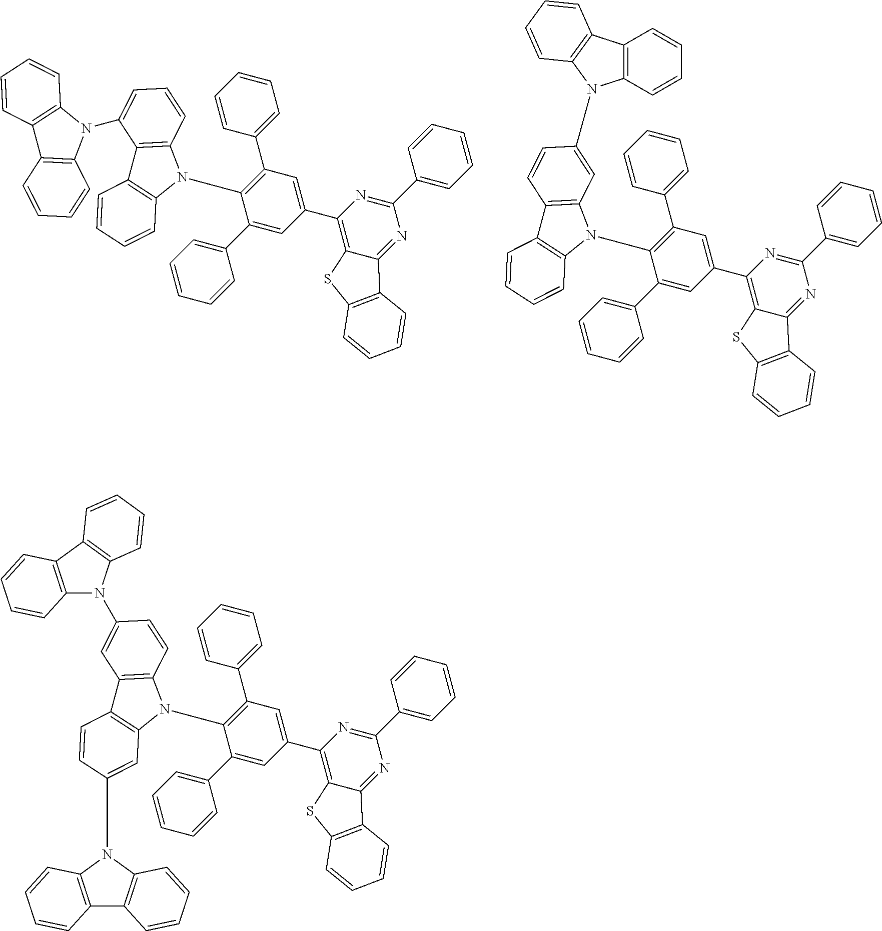 [SMILES: c1ccc(-c2nc(-c3cc(-c4ccccc4)c(-n4c5ccccc5c5c(-n6c7ccccc7c7ccccc76)cccc54)c(-c4ccccc4)c3)c3sc4ccccc4c3n2)cc1 ; c1ccc(-c2nc(-c3cc(-c4ccccc4)c(-n4c5ccccc5c5ccc(-n6c7ccccc7c7ccccc76)cc54)c(-c4ccccc4)c3)c3sc4ccccc4c3n2)cc1 ; c1ccc(-c2nc(-c3cc(-c4ccccc4)c(-n4c5ccc(-n6c7ccccc7c7ccccc76)cc5c5ccc(-n6c7ccccc7c7ccccc76)cc54)c(-c4ccccc4)c3)c3sc4ccccc4c3n2)cc1]

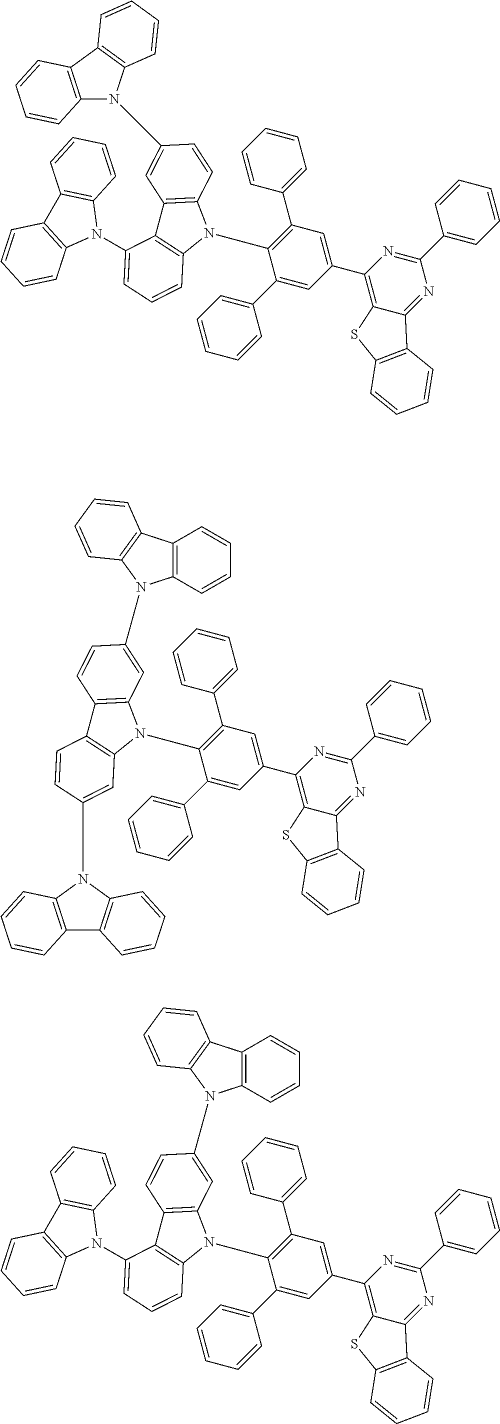 [SMILES: c1ccc(-c2nc(-c3cc(-c4ccccc4)c(-n4c5ccc(-n6c7ccccc7c7ccccc76)cc5c5c(-n6c7ccccc7c7ccccc76)cccc54)c(-c4ccccc4)c3)c3sc4ccccc4c3n2)cc1 ; c1ccc(-c2nc(-c3cc(-c4ccccc4)c(-n4c5cc(-n6c7ccccc7c7ccccc76)ccc5c5ccc(-n6c7ccccc7c7ccccc76)cc54)c(-c4ccccc4)c3)c3sc4ccccc4c3n2)cc1 ; c1ccc(-c2nc(-c3cc(-c4ccccc4)c(-n4c5cc(-n6c7ccccc7c7ccccc76)ccc5c5c(-n6c7ccccc7c7ccccc76)cccc54)c(-c4ccccc4)c3)c3sc4ccccc4c3n2)cc1]

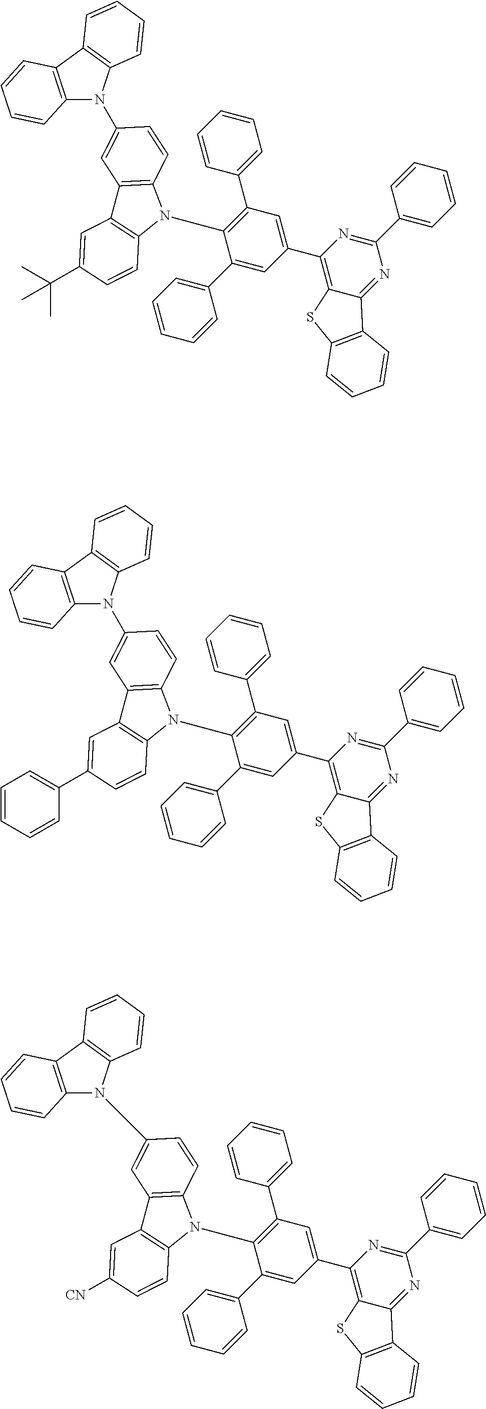

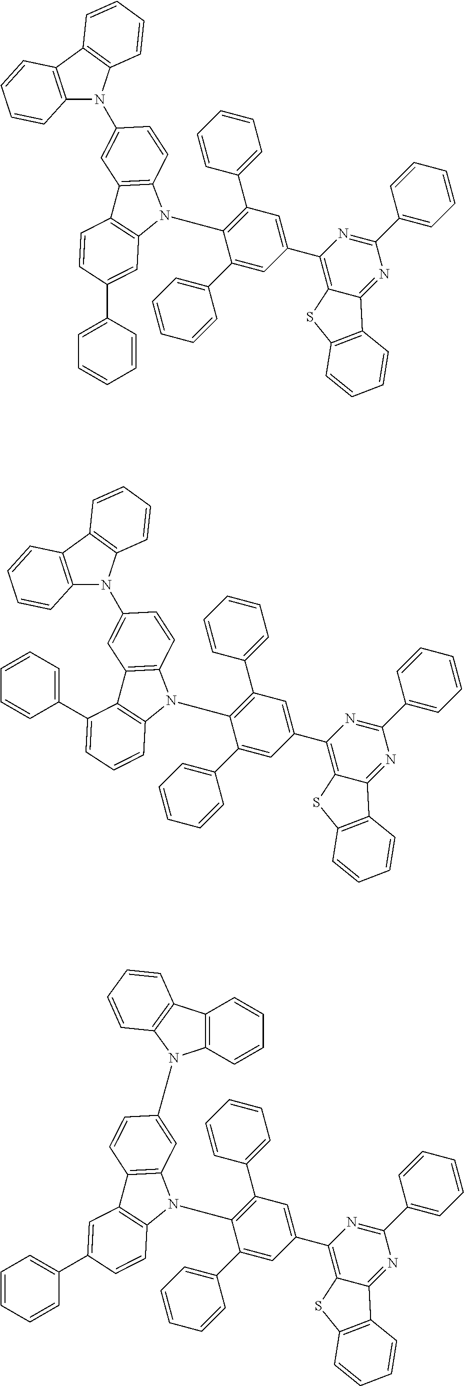 [SMILES: c1ccc(-c2ccc3c4cc(-n5c6ccccc6c6ccccc65)ccc4n(-c4c(-c5ccccc5)cc(-c5nc(-c6ccccc6)nc6c5sc5ccccc56)cc4-c4ccccc4)c3c2)cc1 ; c1ccc(-c2nc(-c3cc(-c4ccccc4)c(-n4c5ccc(-n6c7ccccc7c7ccccc76)cc5c5c(-c6ccccc6)cccc54)c(-c4ccccc4)c3)c3sc4ccccc4c3n2)cc1 ; c1ccc(-c2ccc3c(c2)c2ccc(-n4c5ccccc5c5ccccc54)cc2n3-c2c(-c3ccccc3)cc(-c3nc(-c4ccccc4)nc4c3sc3ccccc34)cc2-c2ccccc2)cc1]

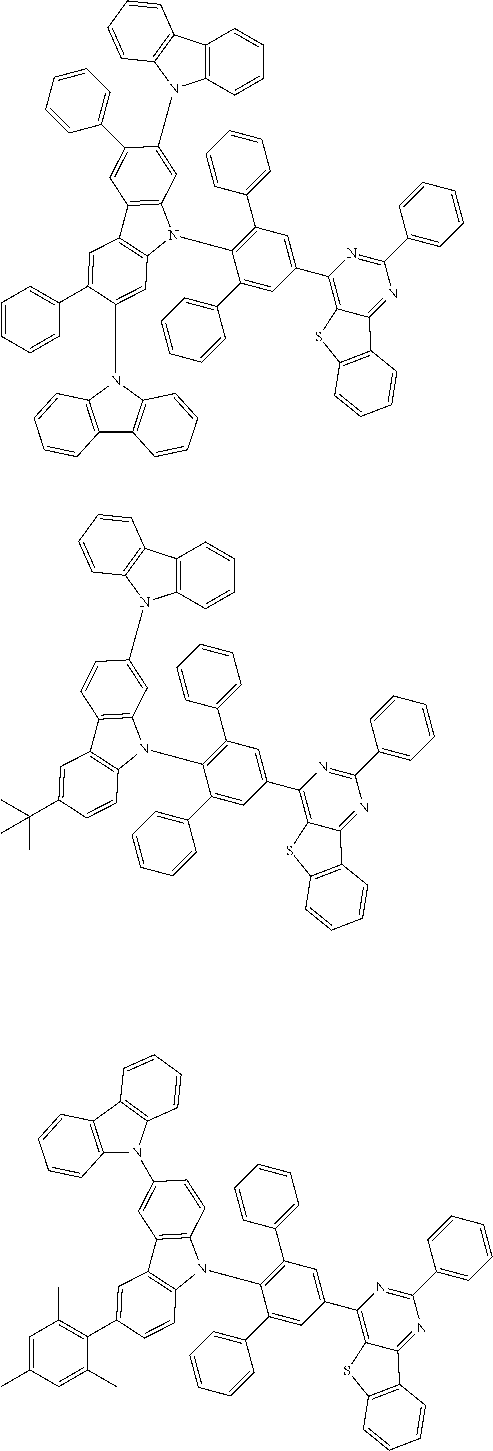 [SMILES: c1ccc(-c2nc(-c3cc(-c4ccccc4)c(-n4c5cc(-n6c7ccccc7c7ccccc76)c(-c6ccccc6)cc5c5cc(-c6ccccc6)c(-n6c7ccccc7c7ccccc76)cc54)c(-c4ccccc4)c3)c3sc4ccccc4c3n2)cc1 ; CC(C)(C)c1ccc2c(c1)c1ccc(-n3c4ccccc4c4ccccc43)cc1n2-c1c(-c2ccccc2)cc(-c2nc(-c3ccccc3)nc3c2sc2ccccc23)cc1-c1ccccc1 ; Cc1cc(C)c(-c2ccc3c(c2)c2cc(-n4c5ccccc5c5ccccc54)ccc2n3-c2c(-c3ccccc3)cc(-c3nc(-c4ccccc4)nc4c3sc3ccccc34)cc2-c2ccccc2)c(C)c1]

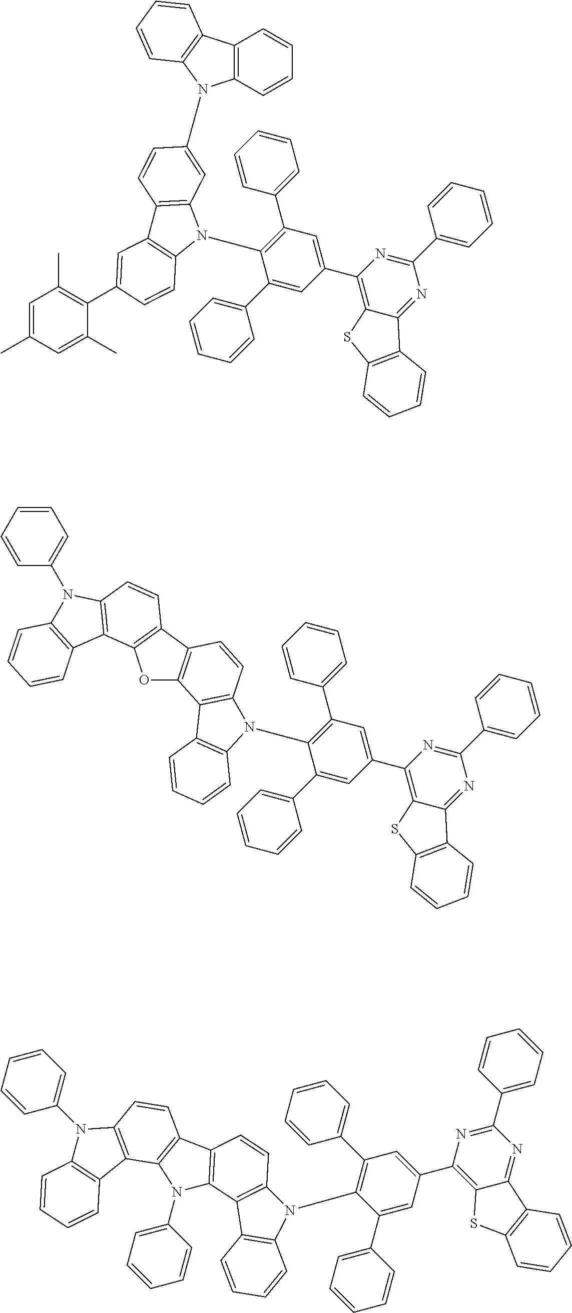 [SMILES: Cc1cc(C)c(-c2ccc3c(c2)c2ccc(-n4c5ccccc5c5ccccc54)cc2n3-c2c(-c3ccccc3)cc(-c3nc(-c4ccccc4)nc4c3sc3ccccc34)cc2-c2ccccc2)c(C)c1 ; c1ccc(-c2nc(-c3cc(-c4ccccc4)c(-n4c5ccccc5c5c6oc7c(ccc8c7c7ccccc7n8-c7ccccc7)c6ccc54)c(-c4ccccc4)c3)c3sc4ccccc4c3n2)cc1 ; c1ccc(-c2nc(-c3cc(-c4ccccc4)c(-n4c5ccccc5c5c4ccc4c6ccc7c(c8ccccc8n7-c7ccccc7)c6n(-c6ccccc6)c45)c(-c4ccccc4)c3)c3sc4ccccc4c3n2)cc1]

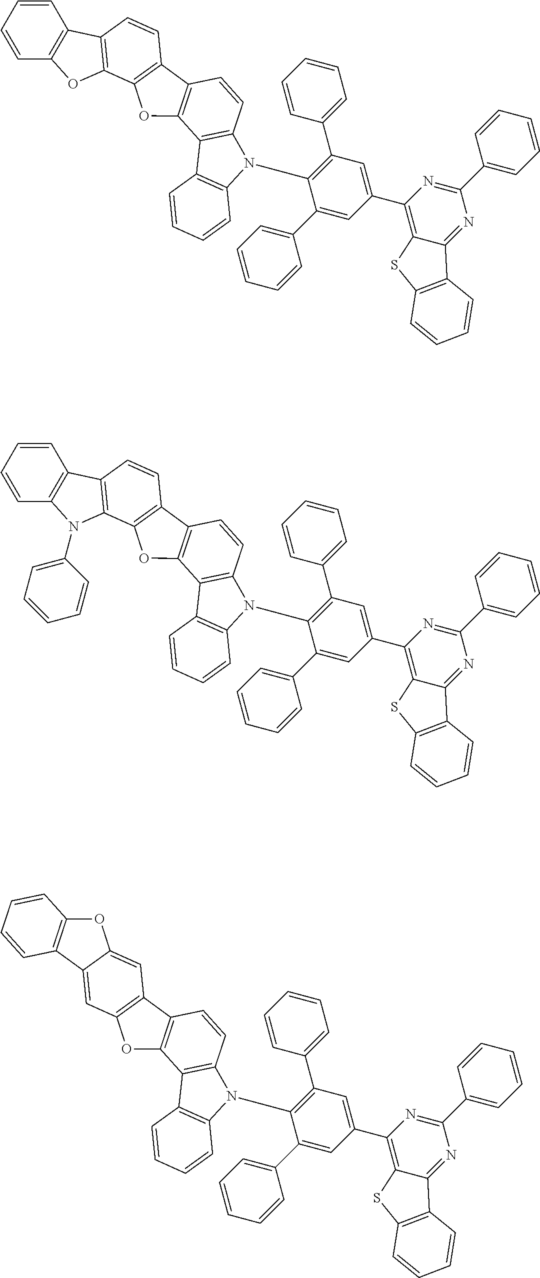 [SMILES: c1ccc(-c2nc(-c3cc(-c4ccccc4)c(-n4c5ccccc5c5c6oc7c(ccc8c9ccccc9oc87)c6ccc54)c(-c4ccccc4)c3)c3sc4ccccc4c3n2)cc1 ; c1ccc(-c2nc(-c3cc(-c4ccccc4)c(-n4c5ccccc5c5c6oc7c(ccc8c9ccccc9n(-c9ccccc9)c87)c6ccc54)c(-c4ccccc4)c3)c3sc4ccccc4c3n2)cc1 ; c1ccc(-c2nc(-c3cc(-c4ccccc4)c(-n4c5ccccc5c5c6oc7cc8c(cc7c6ccc54)oc4ccccc48)c(-c4ccccc4)c3)c3sc4ccccc4c3n2)cc1]

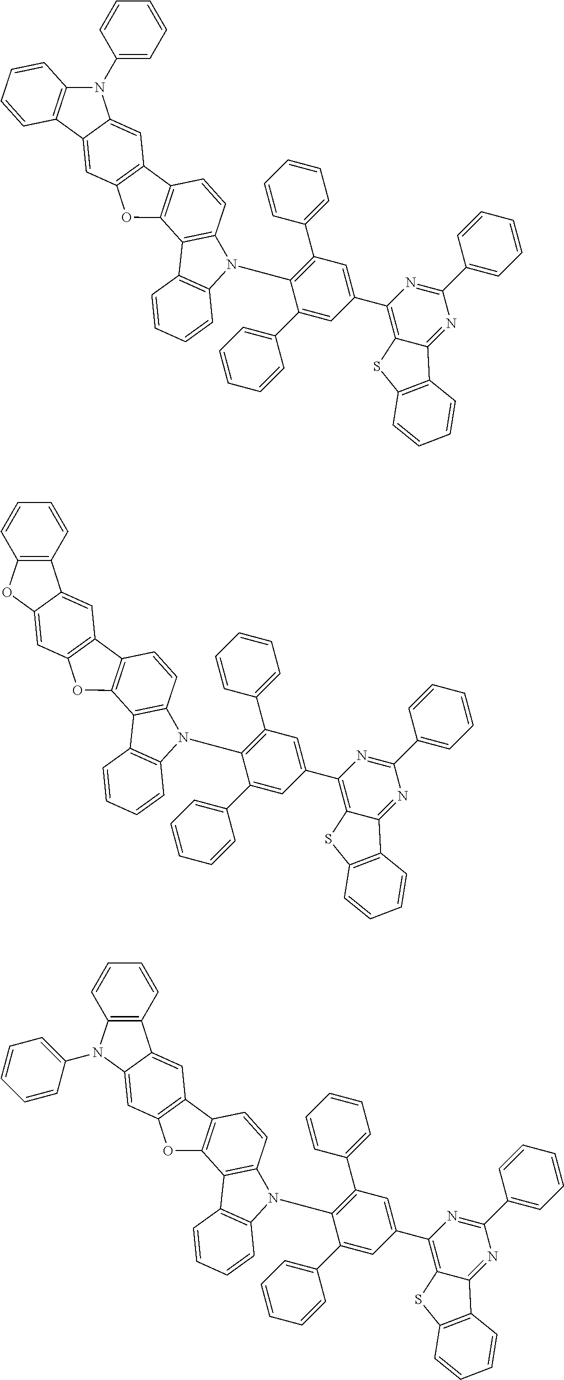 [SMILES: c1ccc(-c2nc(-c3cc(-c4ccccc4)c(-n4c5ccccc5c5c6oc7cc8c9ccccc9n(-c9ccccc9)c8cc7c6ccc54)c(-c4ccccc4)c3)c3sc4ccccc4c3n2)cc1 ; c1ccc(-c2nc(-c3cc(-c4ccccc4)c(-n4c5ccccc5c5c6oc7cc8oc9ccccc9c8cc7c6ccc54)c(-c4ccccc4)c3)c3sc4ccccc4c3n2)cc1 ; c1ccc(-c2nc(-c3cc(-c4ccccc4)c(-n4c5ccccc5c5c6oc7cc8c(cc7c6ccc54)c4ccccc4n8-c4ccccc4)c(-c4ccccc4)c3)c3sc4ccccc4c3n2)cc1]

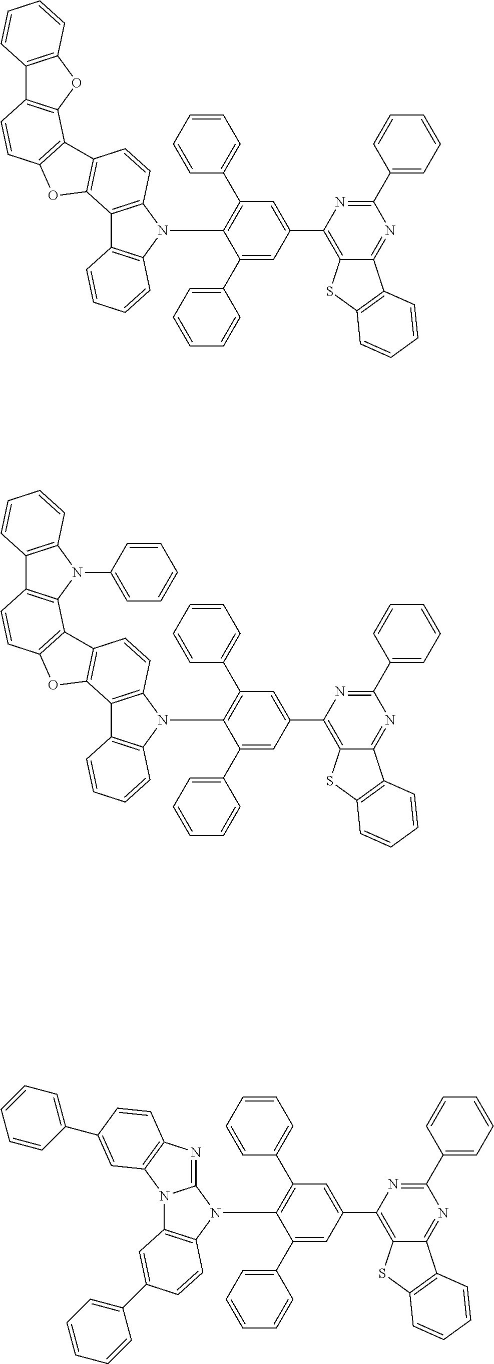 [SMILES: c1ccc(-c2nc(-c3cc(-c4ccccc4)c(-n4c5ccccc5c5c6oc7ccc8c9ccccc9oc8c7c6ccc54)c(-c4ccccc4)c3)c3sc4ccccc4c3n2)cc1 ; c1ccc(-c2nc(-c3cc(-c4ccccc4)c(-n4c5ccccc5c5c6oc7ccc8c9ccccc9n(-c9ccccc9)c8c7c6ccc54)c(-c4ccccc4)c3)c3sc4ccccc4c3n2)cc1 ; c1ccc(-c2ccc3nc4n(-c5c(-c6ccccc6)cc(-c6nc(-c7ccccc7)nc7c6sc6ccccc67)cc5-c5ccccc5)c5ccc(-c6ccccc6)cc5n4c3c2)cc1]

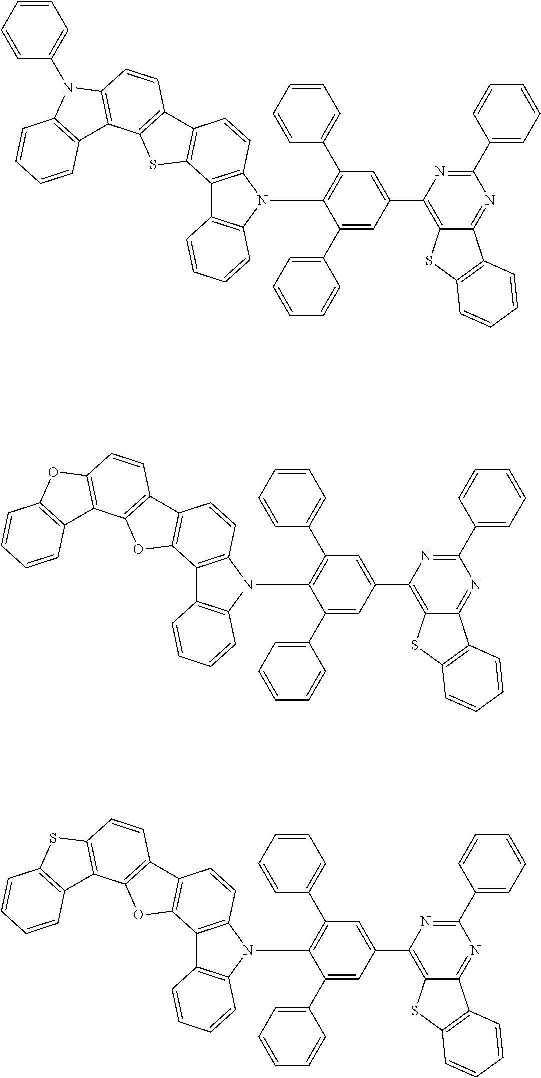 [SMILES: c1ccc(-c2nc(-c3cc(-c4ccccc4)c(-n4c5ccccc5c5c6sc7c(ccc8c7c7ccccc7n8-c7ccccc7)c6ccc54)c(-c4ccccc4)c3)c3sc4ccccc4c3n2)cc1 ; c1ccc(-c2nc(-c3cc(-c4ccccc4)c(-n4c5ccccc5c5c6oc7c(ccc8oc9ccccc9c87)c6ccc54)c(-c4ccccc4)c3)c3sc4ccccc4c3n2)cc1 ; c1ccc(-c2nc(-c3cc(-c4ccccc4)c(-n4c5ccccc5c5c6oc7c(ccc8sc9ccccc9c87)c6ccc54)c(-c4ccccc4)c3)c3sc4ccccc4c3n2)cc1]

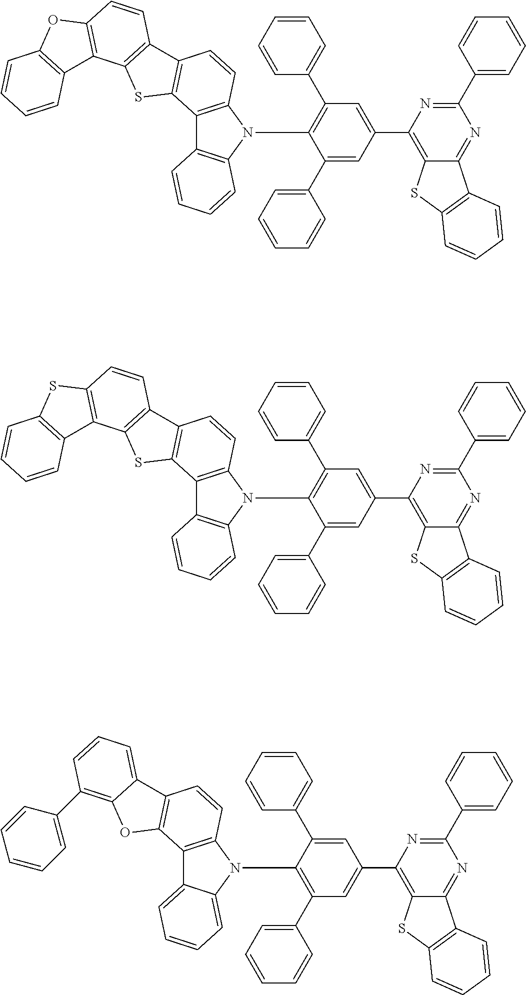 [SMILES: c1ccc(-c2nc(-c3cc(-c4ccccc4)c(-n4c5ccccc5c5c6sc7c(ccc8oc9ccccc9c87)c6ccc54)c(-c4ccccc4)c3)c3sc4ccccc4c3n2)cc1 ; c1ccc(-c2nc(-c3cc(-c4ccccc4)c(-n4c5ccccc5c5c6sc7c(ccc8sc9ccccc9c87)c6ccc54)c(-c4ccccc4)c3)c3sc4ccccc4c3n2)cc1 ; c1ccc(-c2nc(-c3cc(-c4ccccc4)c(-n4c5ccccc5c5c6oc7c(-c8ccccc8)cccc7c6ccc54)c(-c4ccccc4)c3)c3sc4ccccc4c3n2)cc1]

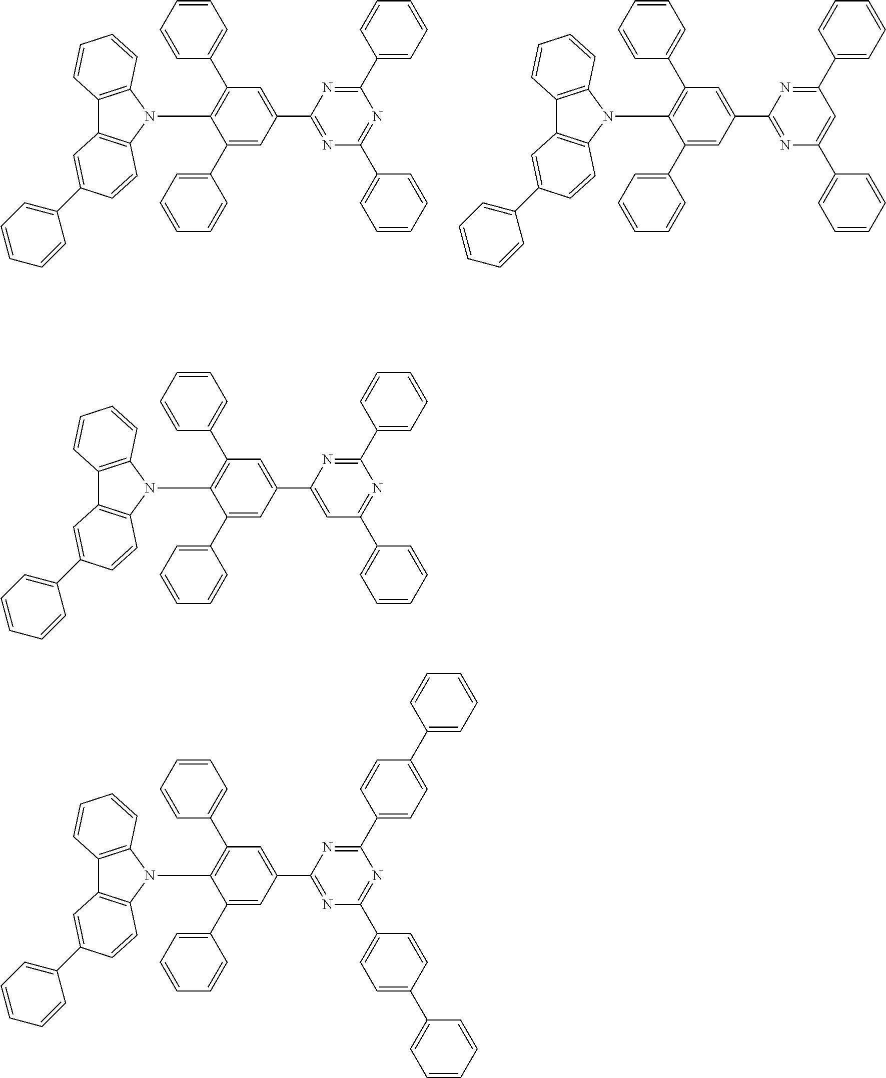

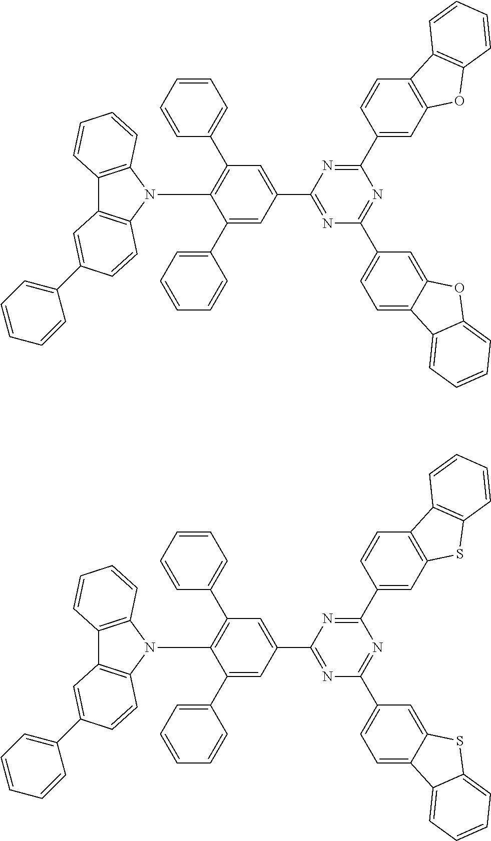 [SMILES: c1ccc(-c2ccc3c(c2)c2ccccc2n3-c2c(-c3ccccc3)cc(-c3nc(-c4ccc5c(c4)oc4ccccc45)nc(-c4ccc5c(c4)oc4ccccc45)n3)cc2-c2ccccc2)cc1 ; c1ccc(-c2ccc3c(c2)c2ccccc2n3-c2c(-c3ccccc3)cc(-c3nc(-c4ccc5c(c4)sc4ccccc45)nc(-c4ccc5c(c4)sc4ccccc45)n3)cc2-c2ccccc2)cc1]

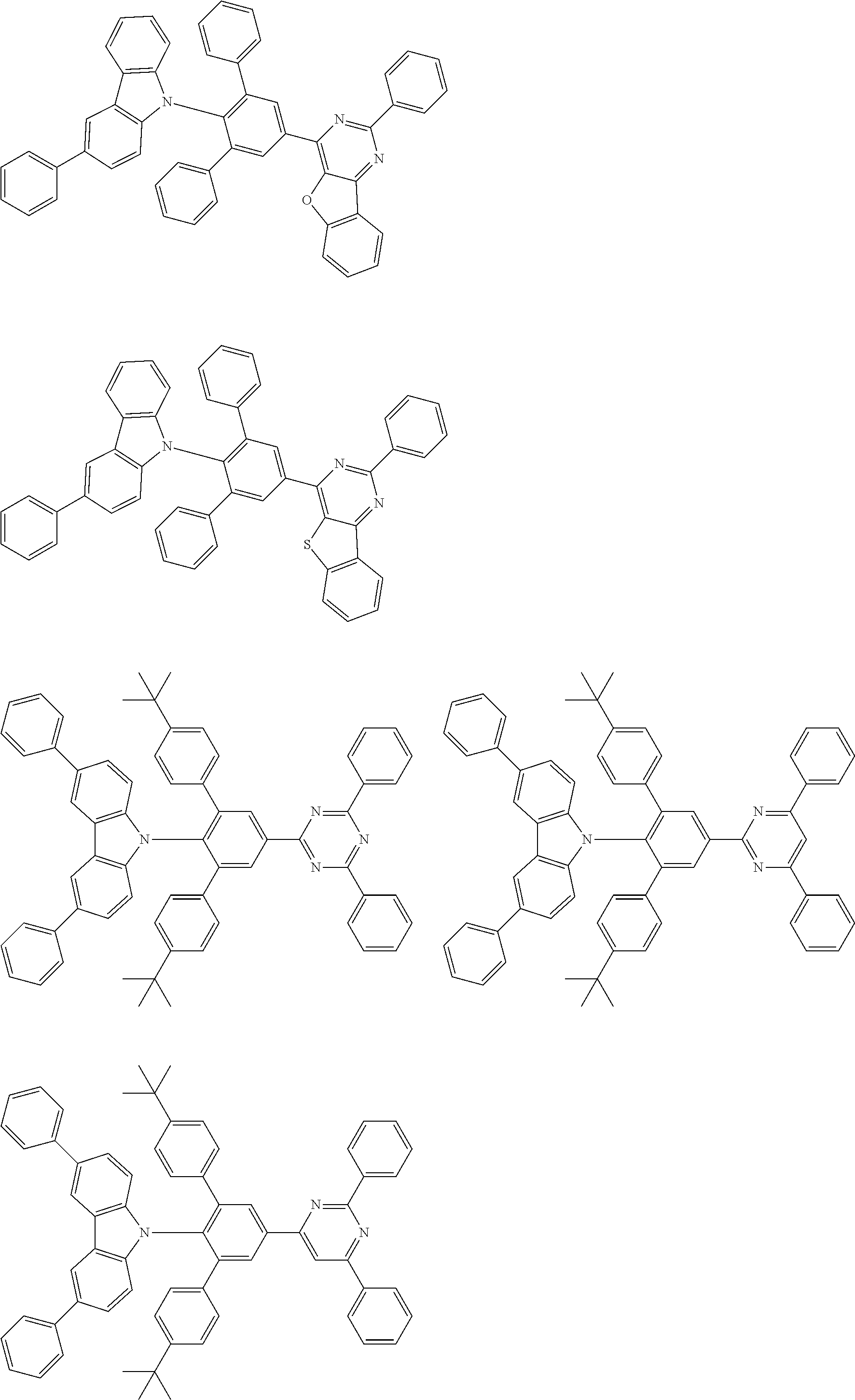

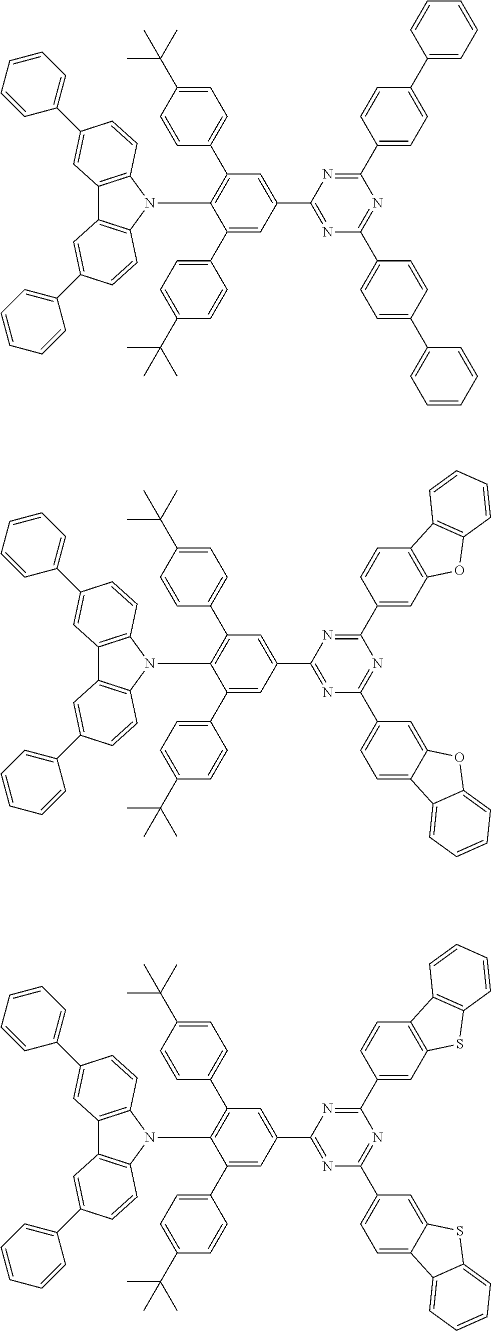 [SMILES: CC(C)(C)c1ccc(-c2cc(-c3nc(-c4ccc(-c5ccccc5)cc4)nc(-c4ccc(-c5ccccc5)cc4)n3)cc(-c3ccc(C(C)(C)C)cc3)c2-n2c3ccc(-c4ccccc4)cc3c3cc(-c4ccccc4)ccc32)cc1 ; CC(C)(C)c1ccc(-c2cc(-c3nc(-c4ccc5c(c4)oc4ccccc45)nc(-c4ccc5c(c4)oc4ccccc45)n3)cc(-c3ccc(C(C)(C)C)cc3)c2-n2c3ccc(-c4ccccc4)cc3c3cc(-c4ccccc4)ccc32)cc1 ; CC(C)(C)c1ccc(-c2cc(-c3nc(-c4ccc5c(c4)sc4ccccc45)nc(-c4ccc5c(c4)sc4ccccc45)n3)cc(-c3ccc(C(C)(C)C)cc3)c2-n2c3ccc(-c4ccccc4)cc3c3cc(-c4ccccc4)ccc32)cc1]

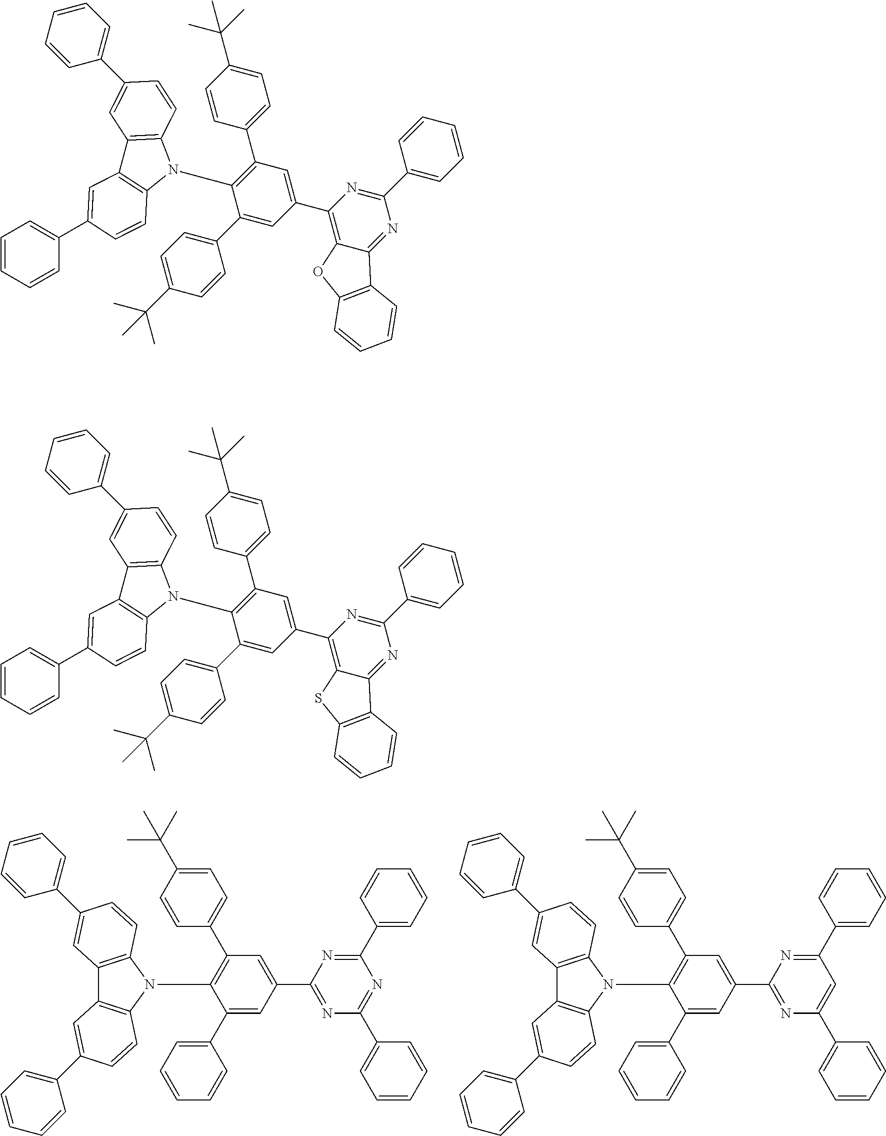

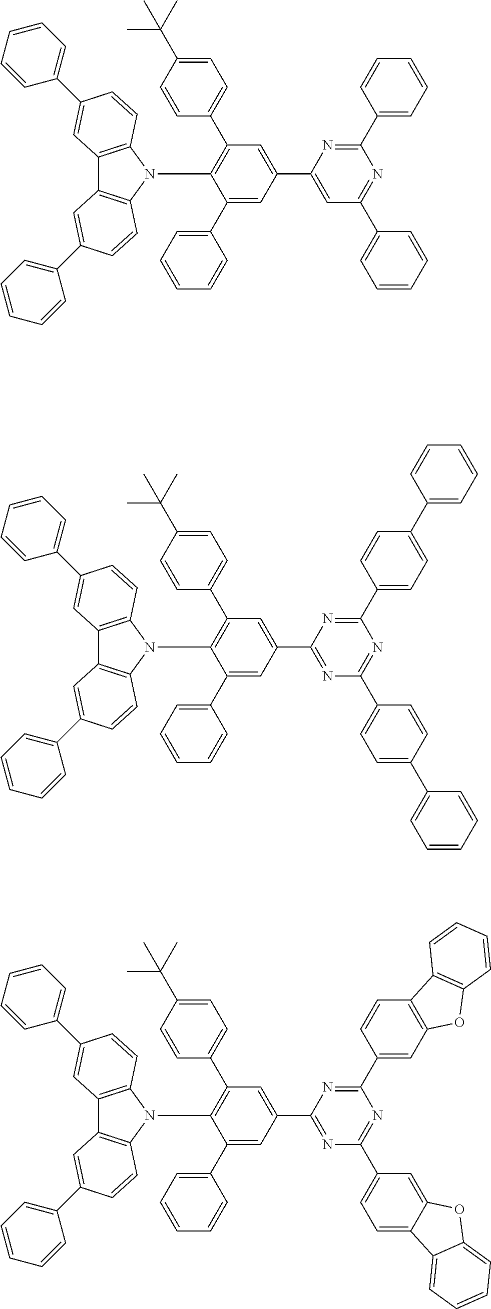 [SMILES: CC(C)(C)c1ccc(-c2cc(-c3cc(-c4ccccc4)nc(-c4ccccc4)n3)cc(-c3ccccc3)c2-n2c3ccc(-c4ccccc4)cc3c3cc(-c4ccccc4)ccc32)cc1 ; CC(C)(C)c1ccc(-c2cc(-c3nc(-c4ccc(-c5ccccc5)cc4)nc(-c4ccc(-c5ccccc5)cc4)n3)cc(-c3ccccc3)c2-n2c3ccc(-c4ccccc4)cc3c3cc(-c4ccccc4)ccc32)cc1 ; CC(C)(C)c1ccc(-c2cc(-c3nc(-c4ccc5c(c4)oc4ccccc45)nc(-c4ccc5c(c4)oc4ccccc45)n3)cc(-c3ccccc3)c2-n2c3ccc(-c4ccccc4)cc3c3cc(-c4ccccc4)ccc32)cc1]

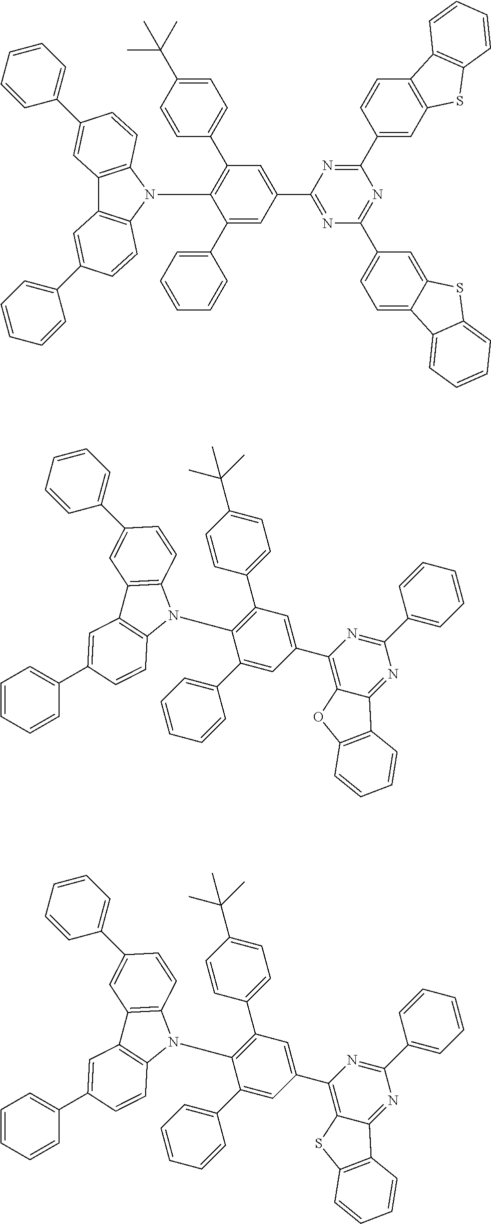 [SMILES: CC(C)(C)c1ccc(-c2cc(-c3nc(-c4ccc5c(c4)sc4ccccc45)nc(-c4ccc5c(c4)sc4ccccc45)n3)cc(-c3ccccc3)c2-n2c3ccc(-c4ccccc4)cc3c3cc(-c4ccccc4)ccc32)cc1 ; CC(C)(C)c1ccc(-c2cc(-c3nc(-c4ccccc4)nc4c3oc3ccccc34)cc(-c3ccccc3)c2-n2c3ccc(-c4ccccc4)cc3c3cc(-c4ccccc4)ccc32)cc1 ; CC(C)(C)c1ccc(-c2cc(-c3nc(-c4ccccc4)nc4c3sc3ccccc34)cc(-c3ccccc3)c2-n2c3ccc(-c4ccccc4)cc3c3cc(-c4ccccc4)ccc32)cc1]

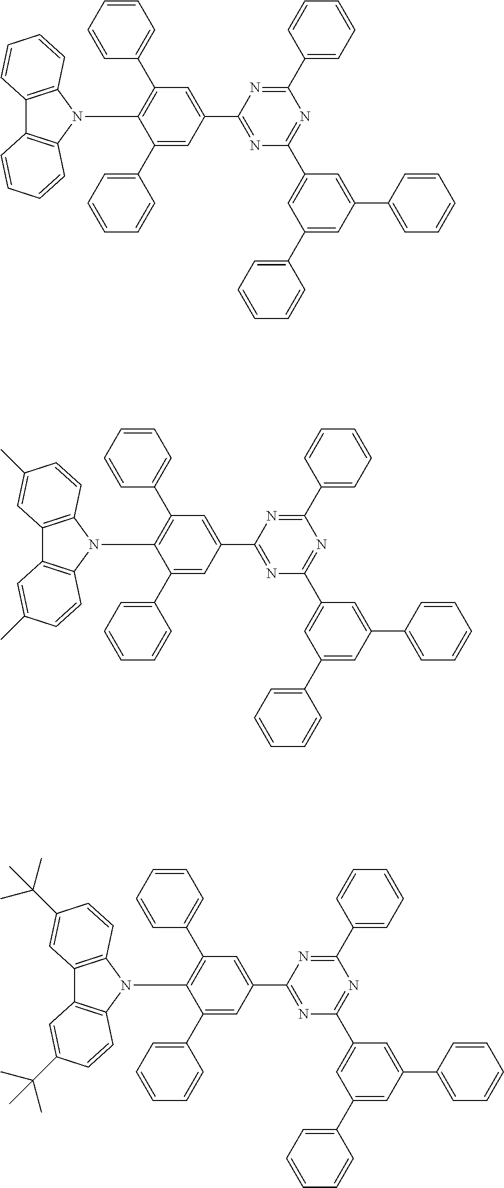 [SMILES: c1ccc(-c2cc(-c3ccccc3)cc(-c3nc(-c4ccccc4)nc(-c4cc(-c5ccccc5)c(-n5c6ccccc6c6ccccc65)c(-c5ccccc5)c4)n3)c2)cc1 ; Cc1ccc2c(c1)c1cc(C)ccc1n2-c1c(-c2ccccc2)cc(-c2nc(-c3ccccc3)nc(-c3cc(-c4ccccc4)cc(-c4ccccc4)c3)n2)cc1-c1ccccc1 ; CC(C)(C)c1ccc2c(c1)c1cc(C(C)(C)C)ccc1n2-c1c(-c2ccccc2)cc(-c2nc(-c3ccccc3)nc(-c3cc(-c4ccccc4)cc(-c4ccccc4)c3)n2)cc1-c1ccccc1]

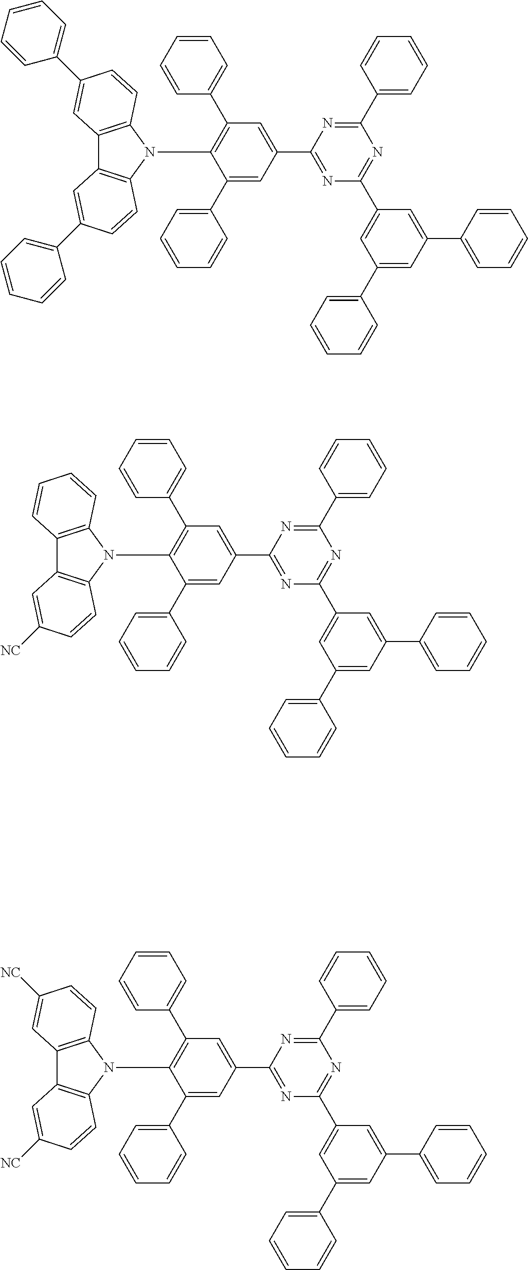 [SMILES: c1ccc(-c2cc(-c3ccccc3)cc(-c3nc(-c4ccccc4)nc(-c4cc(-c5ccccc5)c(-n5c6ccc(-c7ccccc7)cc6c6cc(-c7ccccc7)ccc65)c(-c5ccccc5)c4)n3)c2)cc1 ; N#Cc1ccc2c(c1)c1ccccc1n2-c1c(-c2ccccc2)cc(-c2nc(-c3ccccc3)nc(-c3cc(-c4ccccc4)cc(-c4ccccc4)c3)n2)cc1-c1ccccc1 ; N#Cc1ccc2c(c1)c1cc(C#N)ccc1n2-c1c(-c2ccccc2)cc(-c2nc(-c3ccccc3)nc(-c3cc(-c4ccccc4)cc(-c4ccccc4)c3)n2)cc1-c1ccccc1]

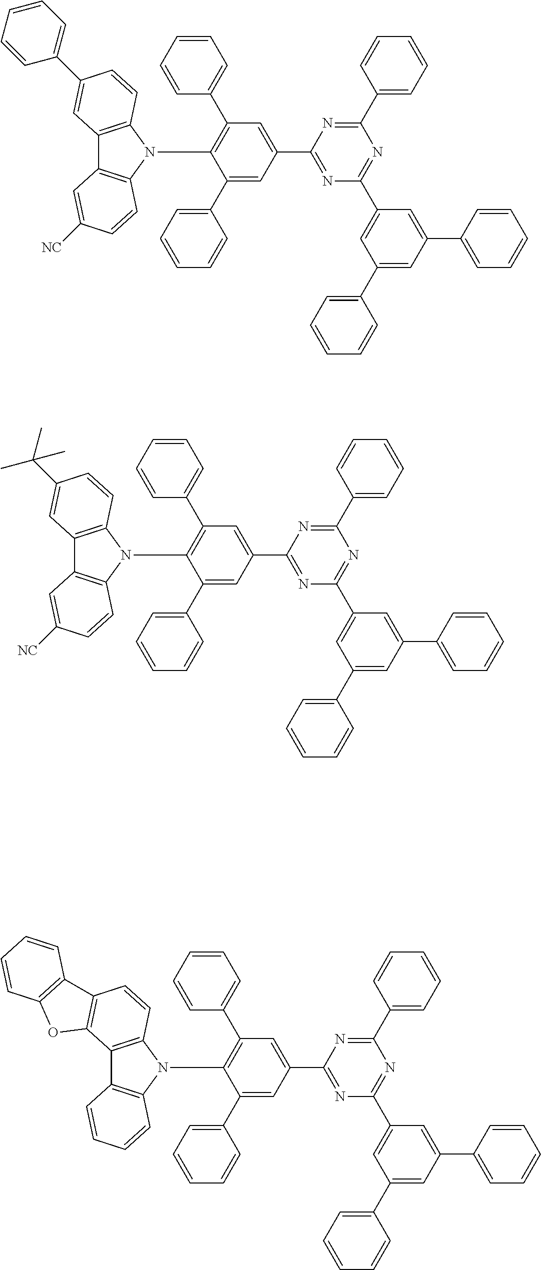 [SMILES: N#Cc1ccc2c(c1)c1cc(-c3ccccc3)ccc1n2-c1c(-c2ccccc2)cc(-c2nc(-c3ccccc3)nc(-c3cc(-c4ccccc4)cc(-c4ccccc4)c3)n2)cc1-c1ccccc1 ; CC(C)(C)c1ccc2c(c1)c1cc(C#N)ccc1n2-c1c(-c2ccccc2)cc(-c2nc(-c3ccccc3)nc(-c3cc(-c4ccccc4)cc(-c4ccccc4)c3)n2)cc1-c1ccccc1 ; c1ccc(-c2cc(-c3ccccc3)cc(-c3nc(-c4ccccc4)nc(-c4cc(-c5ccccc5)c(-n5c6ccccc6c6c7oc8ccccc8c7ccc65)c(-c5ccccc5)c4)n3)c2)cc1]

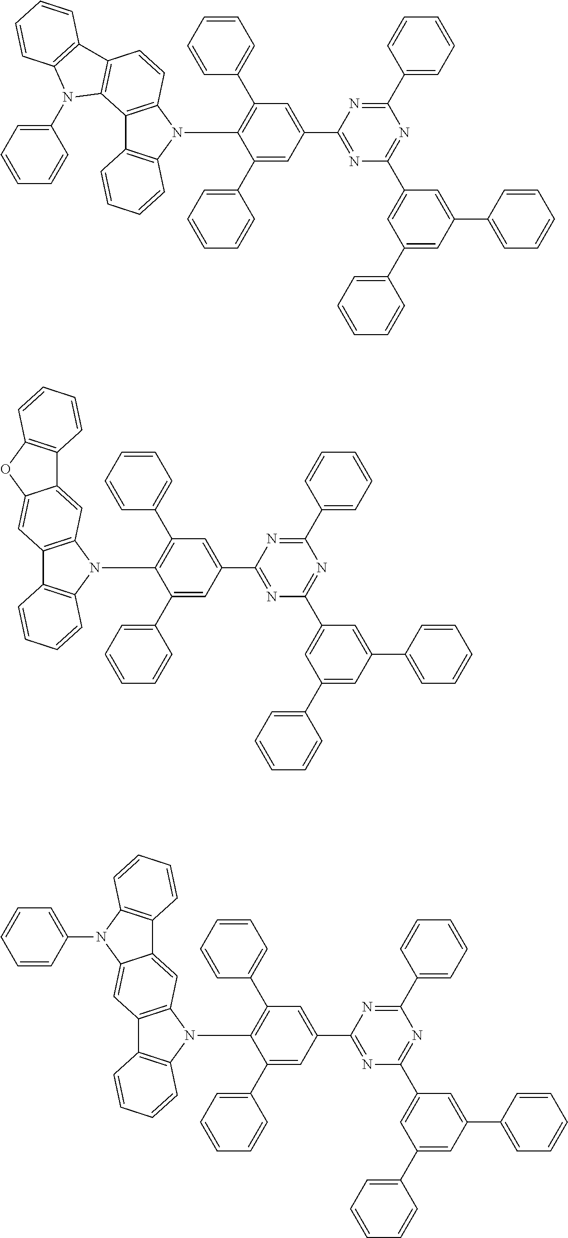 [SMILES: c1ccc(-c2cc(-c3ccccc3)cc(-c3nc(-c4ccccc4)nc(-c4cc(-c5ccccc5)c(-n5c6ccccc6c6c5ccc5c7ccccc7n(-c7ccccc7)c56)c(-c5ccccc5)c4)n3)c2)cc1 ; c1ccc(-c2cc(-c3ccccc3)cc(-c3nc(-c4ccccc4)nc(-c4cc(-c5ccccc5)c(-n5c6ccccc6c6cc7oc8ccccc8c7cc65)c(-c5ccccc5)c4)n3)c2)cc1 ; c1ccc(-c2cc(-c3ccccc3)cc(-c3nc(-c4ccccc4)nc(-c4cc(-c5ccccc5)c(-n5c6ccccc6c6cc7c(cc65)c5ccccc5n7-c5ccccc5)c(-c5ccccc5)c4)n3)c2)cc1]

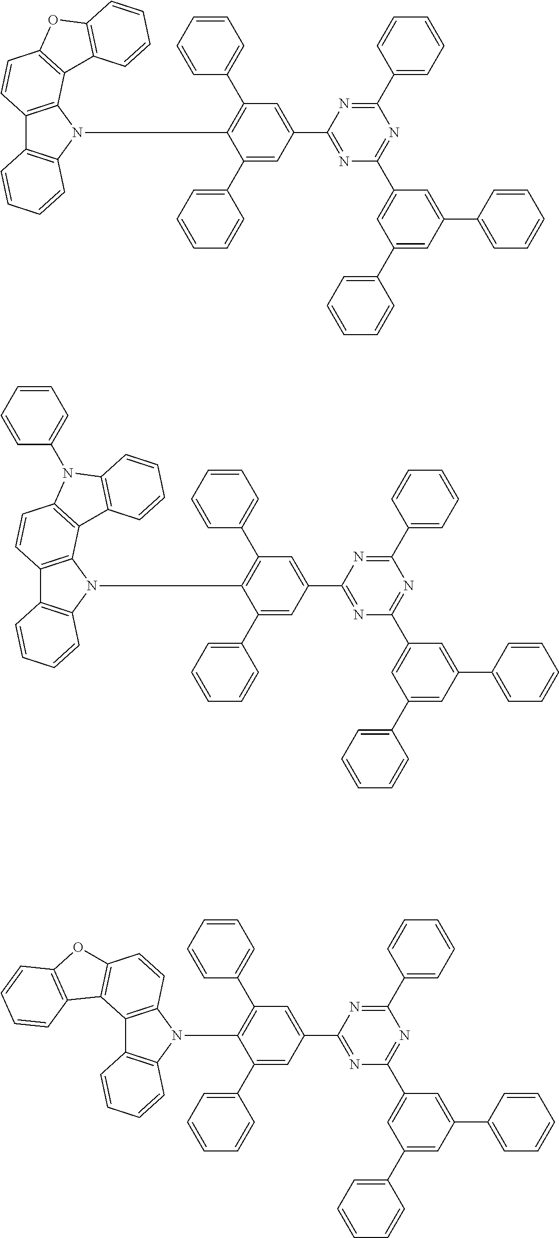 [SMILES: c1ccc(-c2cc(-c3ccccc3)cc(-c3nc(-c4ccccc4)nc(-c4cc(-c5ccccc5)c(-n5c6ccccc6c6ccc7oc8ccccc8c7c65)c(-c5ccccc5)c4)n3)c2)cc1 ; c1ccc(-c2cc(-c3ccccc3)cc(-c3nc(-c4ccccc4)nc(-c4cc(-c5ccccc5)c(-n5c6ccccc6c6ccc7c(c8ccccc8n7-c7ccccc7)c65)c(-c5ccccc5)c4)n3)c2)cc1 ; c1ccc(-c2cc(-c3ccccc3)cc(-c3nc(-c4ccccc4)nc(-c4cc(-c5ccccc5)c(-n5c6ccccc6c6c7c(ccc65)oc5ccccc57)c(-c5ccccc5)c4)n3)c2)cc1]

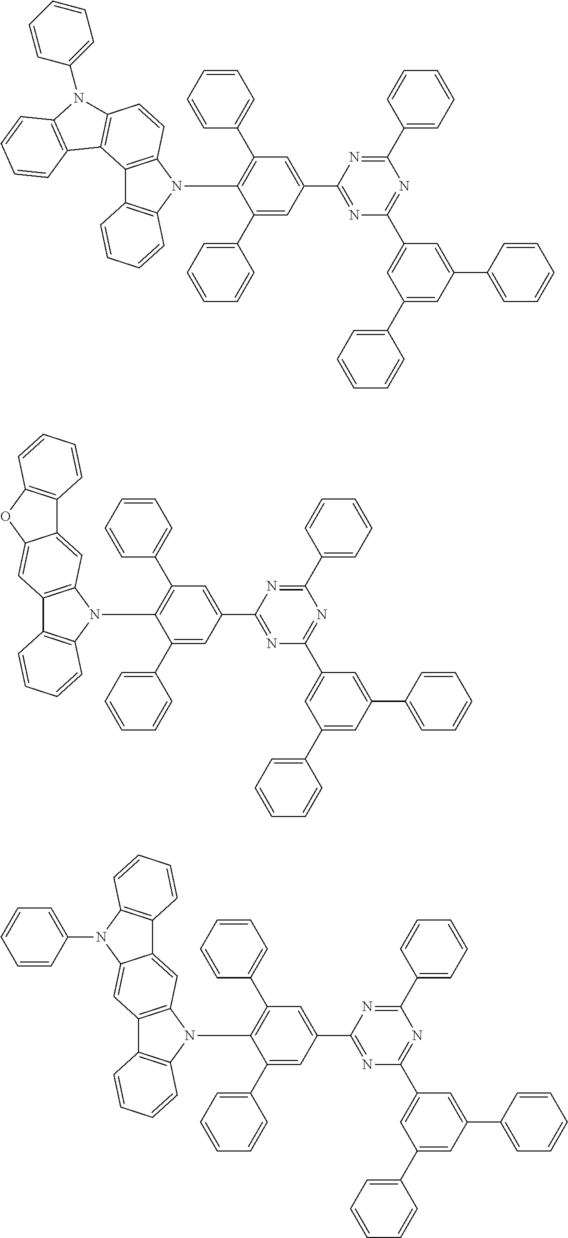 [SMILES: c1ccc(-c2cc(-c3ccccc3)cc(-c3nc(-c4ccccc4)nc(-c4cc(-c5ccccc5)c(-n5c6ccccc6c6c7c8ccccc8n(-c8ccccc8)c7ccc65)c(-c5ccccc5)c4)n3)c2)cc1 ; c1ccc(-c2cc(-c3ccccc3)cc(-c3nc(-c4ccccc4)nc(-c4cc(-c5ccccc5)c(-n5c6ccccc6c6cc7oc8ccccc8c7cc65)c(-c5ccccc5)c4)n3)c2)cc1 ; c1ccc(-c2cc(-c3ccccc3)cc(-c3nc(-c4ccccc4)nc(-c4cc(-c5ccccc5)c(-n5c6ccccc6c6cc7c(cc65)c5ccccc5n7-c5ccccc5)c(-c5ccccc5)c4)n3)c2)cc1]

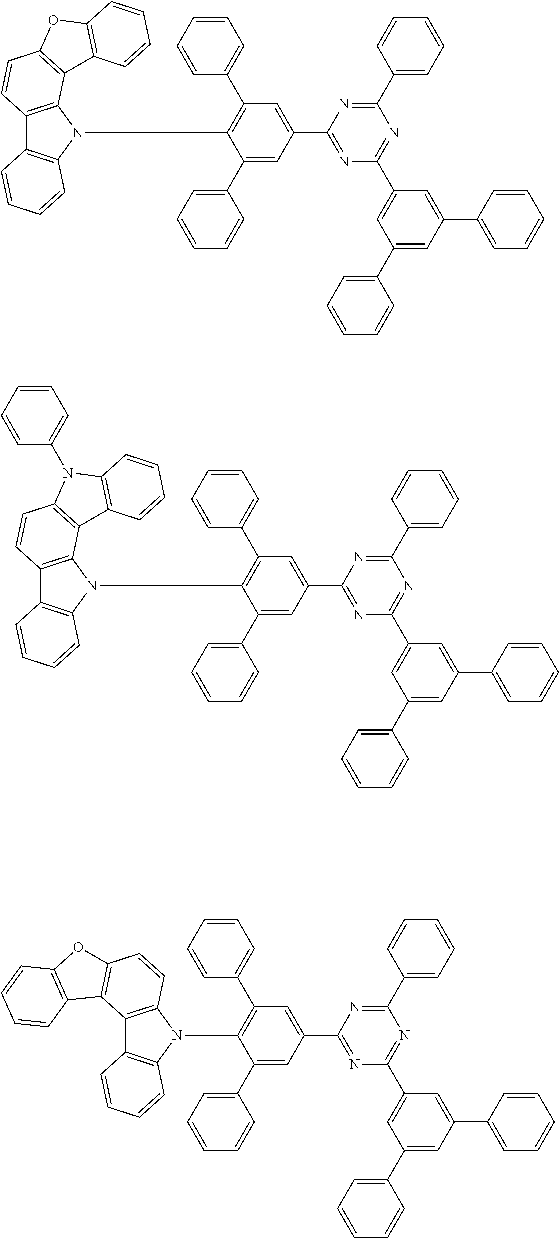 [SMILES: c1ccc(-c2cc(-c3ccccc3)cc(-c3nc(-c4ccccc4)nc(-c4cc(-c5ccccc5)c(-n5c6ccccc6c6ccc7oc8ccccc8c7c65)c(-c5ccccc5)c4)n3)c2)cc1 ; c1ccc(-c2cc(-c3ccccc3)cc(-c3nc(-c4ccccc4)nc(-c4cc(-c5ccccc5)c(-n5c6ccccc6c6ccc7c(c8ccccc8n7-c7ccccc7)c65)c(-c5ccccc5)c4)n3)c2)cc1 ; c1ccc(-c2cc(-c3ccccc3)cc(-c3nc(-c4ccccc4)nc(-c4cc(-c5ccccc5)c(-n5c6ccccc6c6c7c(ccc65)oc5ccccc57)c(-c5ccccc5)c4)n3)c2)cc1]

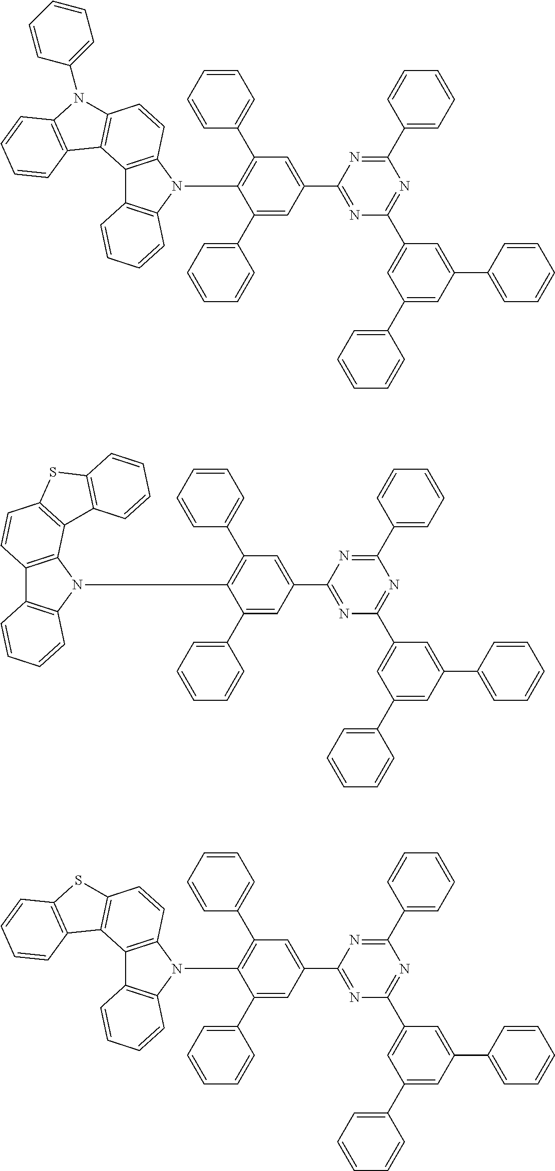 [SMILES: c1ccc(-c2cc(-c3ccccc3)cc(-c3nc(-c4ccccc4)nc(-c4cc(-c5ccccc5)c(-n5c6ccccc6c6c7c8ccccc8n(-c8ccccc8)c7ccc65)c(-c5ccccc5)c4)n3)c2)cc1 ; c1ccc(-c2cc(-c3ccccc3)cc(-c3nc(-c4ccccc4)nc(-c4cc(-c5ccccc5)c(-n5c6ccccc6c6ccc7sc8ccccc8c7c65)c(-c5ccccc5)c4)n3)c2)cc1 ; c1ccc(-c2cc(-c3ccccc3)cc(-c3nc(-c4ccccc4)nc(-c4cc(-c5ccccc5)c(-n5c6ccccc6c6c7c(ccc65)sc5ccccc57)c(-c5ccccc5)c4)n3)c2)cc1]

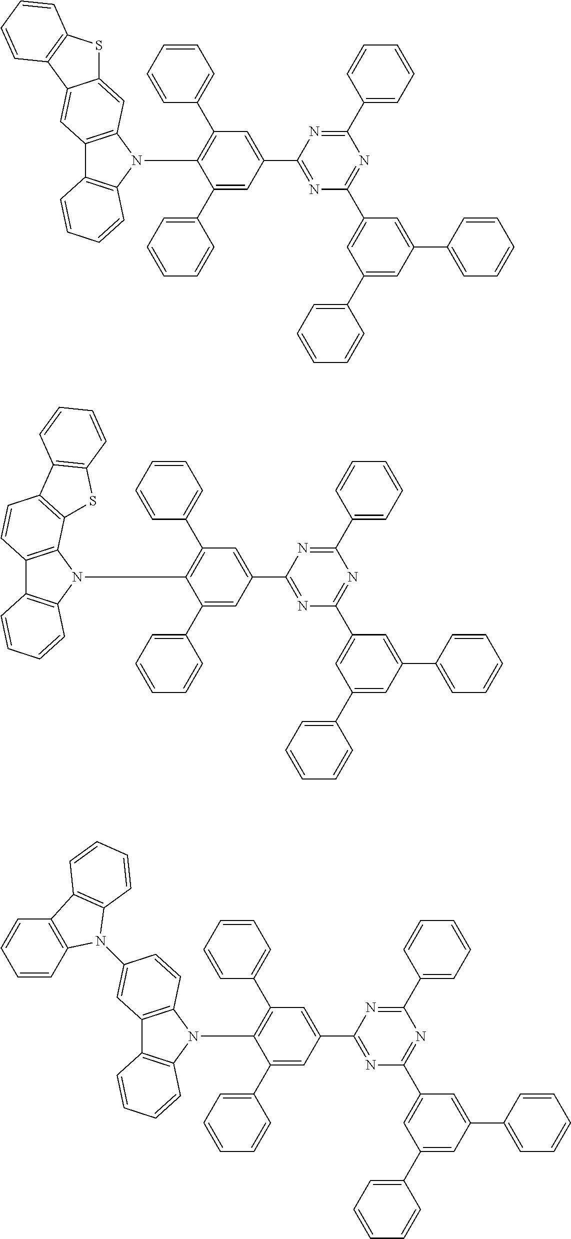 [SMILES: c1ccc(-c2cc(-c3ccccc3)cc(-c3nc(-c4ccccc4)nc(-c4cc(-c5ccccc5)c(-n5c6ccccc6c6cc7c(cc65)sc5ccccc57)c(-c5ccccc5)c4)n3)c2)cc1 ; c1ccc(-c2cc(-c3ccccc3)cc(-c3nc(-c4ccccc4)nc(-c4cc(-c5ccccc5)c(-n5c6ccccc6c6ccc7c8ccccc8sc7c65)c(-c5ccccc5)c4)n3)c2)cc1 ; c1ccc(-c2cc(-c3ccccc3)cc(-c3nc(-c4ccccc4)nc(-c4cc(-c5ccccc5)c(-n5c6ccccc6c6cc(-n7c8ccccc8c8ccccc87)ccc65)c(-c5ccccc5)c4)n3)c2)cc1]

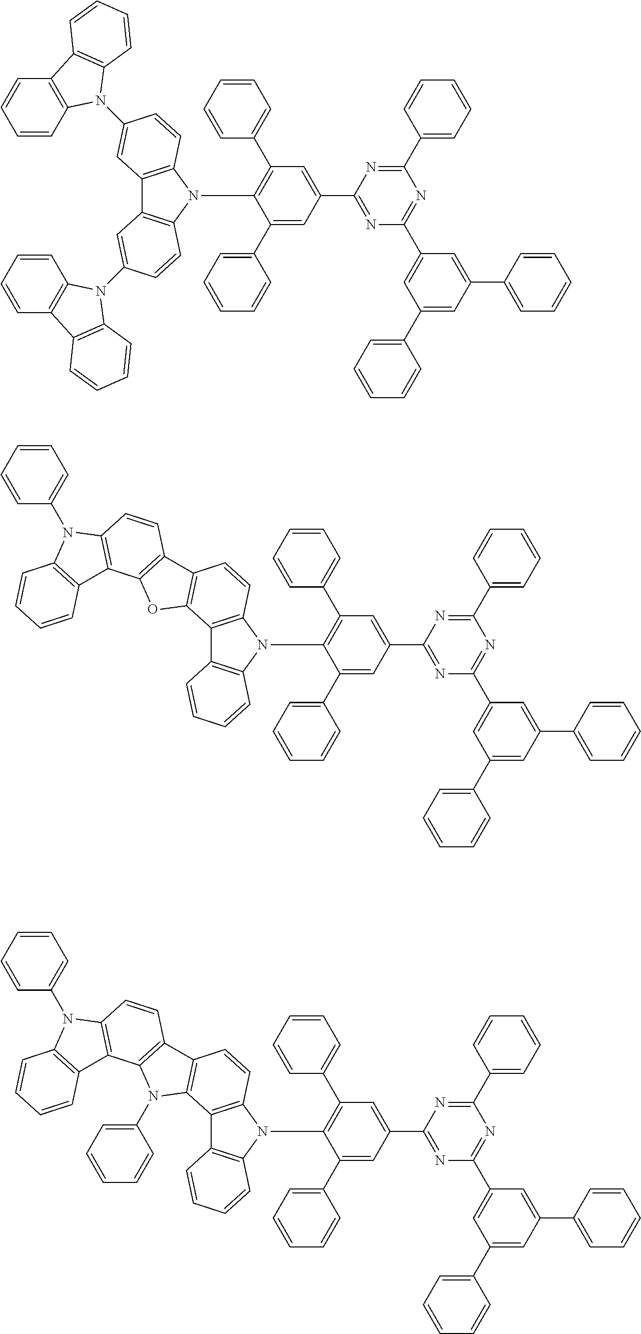 [SMILES: c1ccc(-c2cc(-c3ccccc3)cc(-c3nc(-c4ccccc4)nc(-c4cc(-c5ccccc5)c(-n5c6ccc(-n7c8ccccc8c8ccccc87)cc6c6cc(-n7c8ccccc8c8ccccc87)ccc65)c(-c5ccccc5)c4)n3)c2)cc1 ; c1ccc(-c2cc(-c3ccccc3)cc(-c3nc(-c4ccccc4)nc(-c4cc(-c5ccccc5)c(-n5c6ccccc6c6c7oc8c(ccc9c8c8ccccc8n9-c8ccccc8)c7ccc65)c(-c5ccccc5)c4)n3)c2)cc1 ; c1ccc(-c2cc(-c3ccccc3)cc(-c3nc(-c4ccccc4)nc(-c4cc(-c5ccccc5)c(-n5c6ccccc6c6c5ccc5c7ccc8c(c9ccccc9n8-c8ccccc8)c7n(-c7ccccc7)c56)c(-c5ccccc5)c4)n3)c2)cc1]

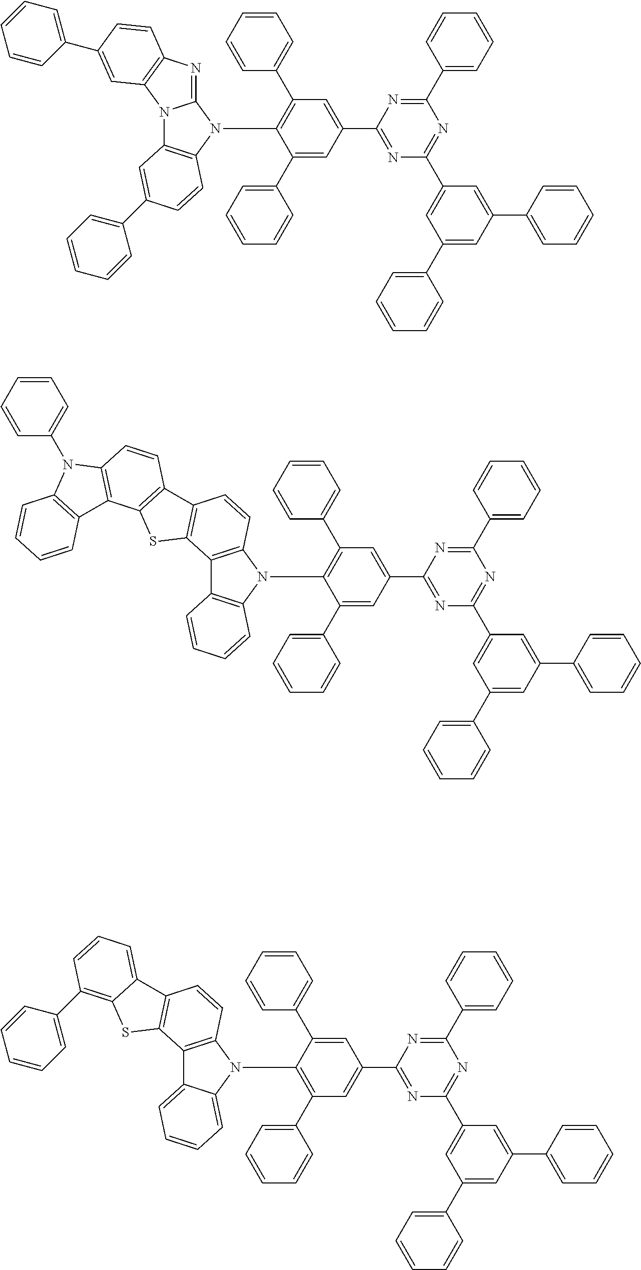 [SMILES: c1ccc(-c2cc(-c3ccccc3)cc(-c3nc(-c4ccccc4)nc(-c4cc(-c5ccccc5)c(-n5c6ccc(-c7ccccc7)cc6n6c7cc(-c8ccccc8)ccc7nc56)c(-c5ccccc5)c4)n3)c2)cc1 ; c1ccc(-c2cc(-c3ccccc3)cc(-c3nc(-c4ccccc4)nc(-c4cc(-c5ccccc5)c(-n5c6ccccc6c6c7sc8c(ccc9c8c8ccccc8n9-c8ccccc8)c7ccc65)c(-c5ccccc5)c4)n3)c2)cc1 ; c1ccc(-c2cc(-c3ccccc3)cc(-c3nc(-c4ccccc4)nc(-c4cc(-c5ccccc5)c(-n5c6ccccc6c6c7sc8c(-c9ccccc9)cccc8c7ccc65)c(-c5ccccc5)c4)n3)c2)cc1]

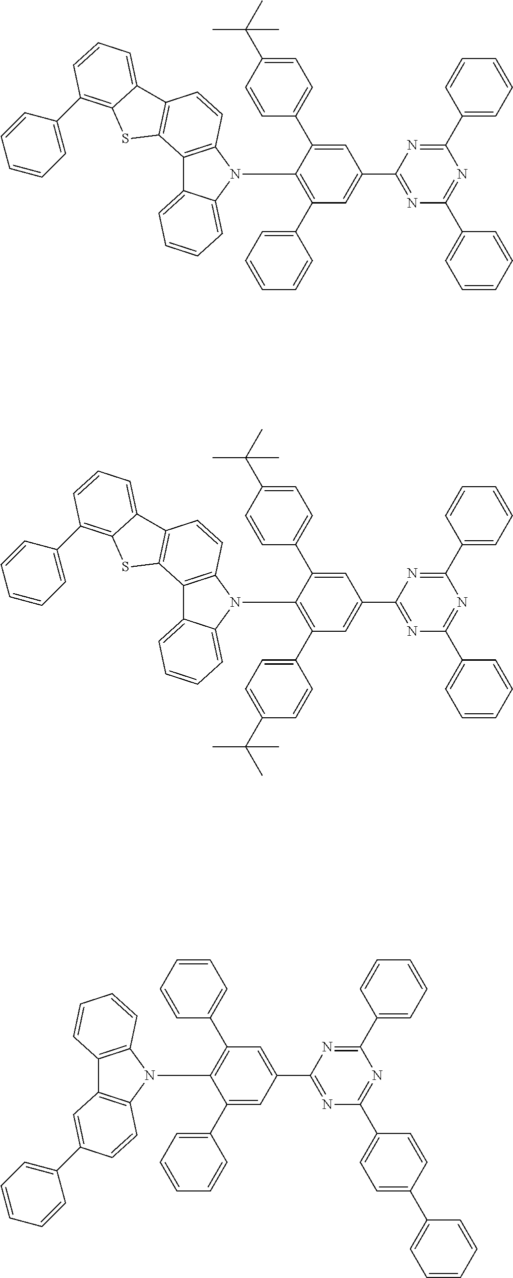 [SMILES: CC(C)(C)c1ccc(-c2cc(-c3nc(-c4ccccc4)nc(-c4ccccc4)n3)cc(-c3ccccc3)c2-n2c3ccccc3c3c4sc5c(-c6ccccc6)cccc5c4ccc32)cc1 ; CC(C)(C)c1ccc(-c2cc(-c3nc(-c4ccccc4)nc(-c4ccccc4)n3)cc(-c3ccc(C(C)(C)C)cc3)c2-n2c3ccccc3c3c4sc5c(-c6ccccc6)cccc5c4ccc32)cc1 ; c1ccc(-c2ccc(-c3nc(-c4ccccc4)nc(-c4cc(-c5ccccc5)c(-n5c6ccccc6c6cc(-c7ccccc7)ccc65)c(-c5ccccc5)c4)n3)cc2)cc1]

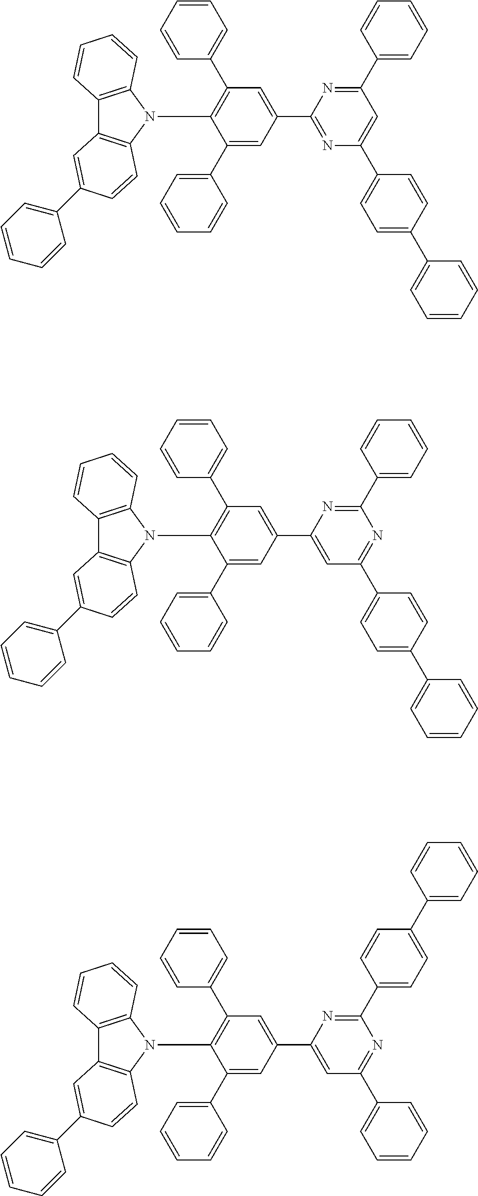 [SMILES: c1ccc(-c2ccc(-c3cc(-c4ccccc4)nc(-c4cc(-c5ccccc5)c(-n5c6ccccc6c6cc(-c7ccccc7)ccc65)c(-c5ccccc5)c4)n3)cc2)cc1 ; c1ccc(-c2ccc(-c3cc(-c4cc(-c5ccccc5)c(-n5c6ccccc6c6cc(-c7ccccc7)ccc65)c(-c5ccccc5)c4)nc(-c4ccccc4)n3)cc2)cc1 ; c1ccc(-c2ccc(-c3nc(-c4ccccc4)cc(-c4cc(-c5ccccc5)c(-n5c6ccccc6c6cc(-c7ccccc7)ccc65)c(-c5ccccc5)c4)n3)cc2)cc1]

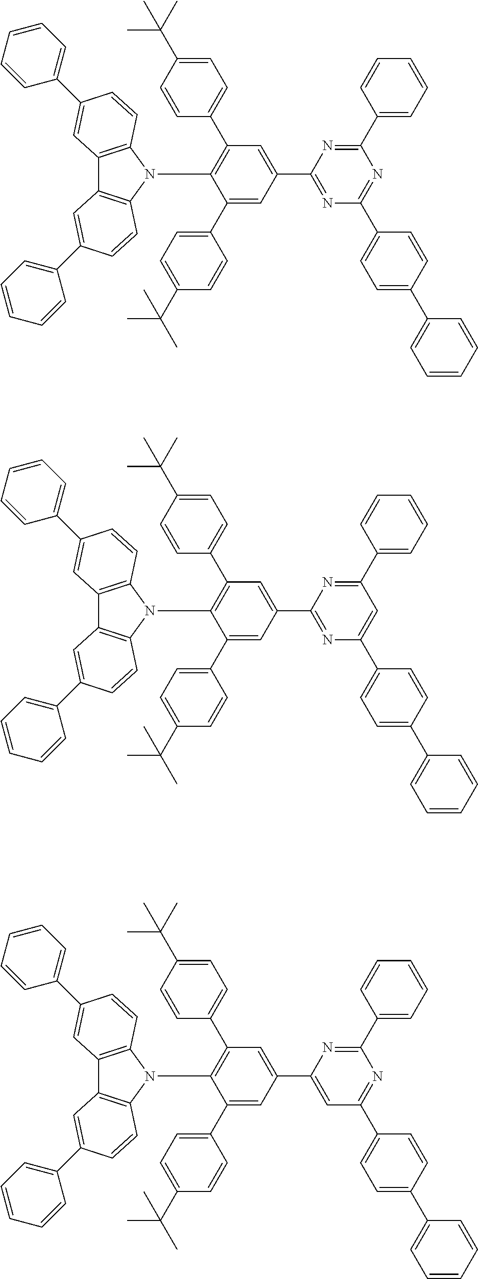 [SMILES: CC(C)(C)c1ccc(-c2cc(-c3nc(-c4ccccc4)nc(-c4ccc(-c5ccccc5)cc4)n3)cc(-c3ccc(C(C)(C)C)cc3)c2-n2c3ccc(-c4ccccc4)cc3c3cc(-c4ccccc4)ccc32)cc1 ; CC(C)(C)c1ccc(-c2cc(-c3nc(-c4ccccc4)cc(-c4ccc(-c5ccccc5)cc4)n3)cc(-c3ccc(C(C)(C)C)cc3)c2-n2c3ccc(-c4ccccc4)cc3c3cc(-c4ccccc4)ccc32)cc1 ; CC(C)(C)c1ccc(-c2cc(-c3cc(-c4ccc(-c5ccccc5)cc4)nc(-c4ccccc4)n3)cc(-c3ccc(C(C)(C)C)cc3)c2-n2c3ccc(-c4ccccc4)cc3c3cc(-c4ccccc4)ccc32)cc1]

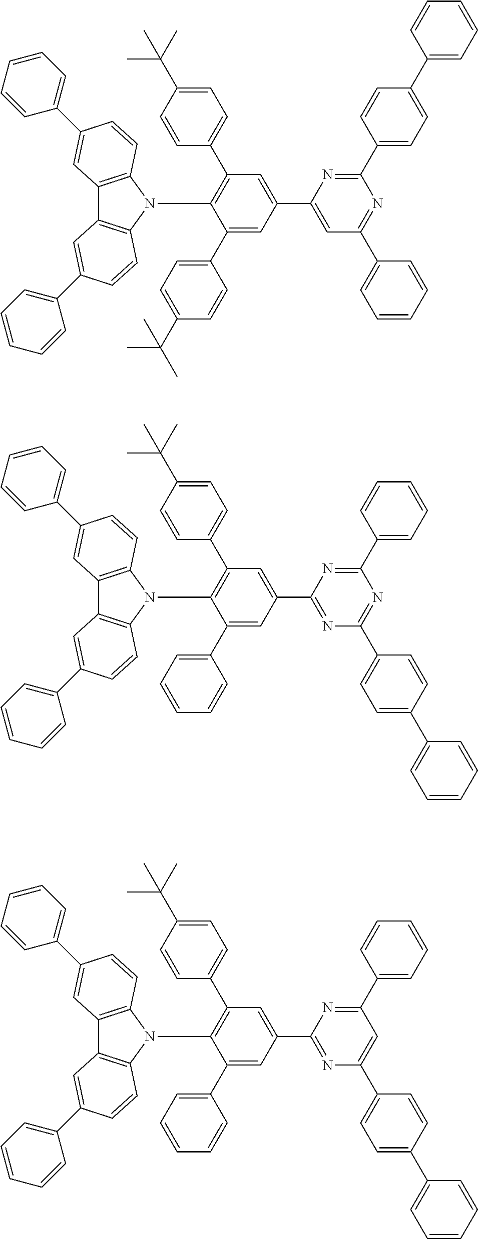 [SMILES: CC(C)(C)c1ccc(-c2cc(-c3cc(-c4ccccc4)nc(-c4ccc(-c5ccccc5)cc4)n3)cc(-c3ccc(C(C)(C)C)cc3)c2-n2c3ccc(-c4ccccc4)cc3c3cc(-c4ccccc4)ccc32)cc1 ; CC(C)(C)c1ccc(-c2cc(-c3nc(-c4ccccc4)nc(-c4ccc(-c5ccccc5)cc4)n3)cc(-c3ccccc3)c2-n2c3ccc(-c4ccccc4)cc3c3cc(-c4ccccc4)ccc32)cc1 ; CC(C)(C)c1ccc(-c2cc(-c3nc(-c4ccccc4)cc(-c4ccc(-c5ccccc5)cc4)n3)cc(-c3ccccc3)c2-n2c3ccc(-c4ccccc4)cc3c3cc(-c4ccccc4)ccc32)cc1]

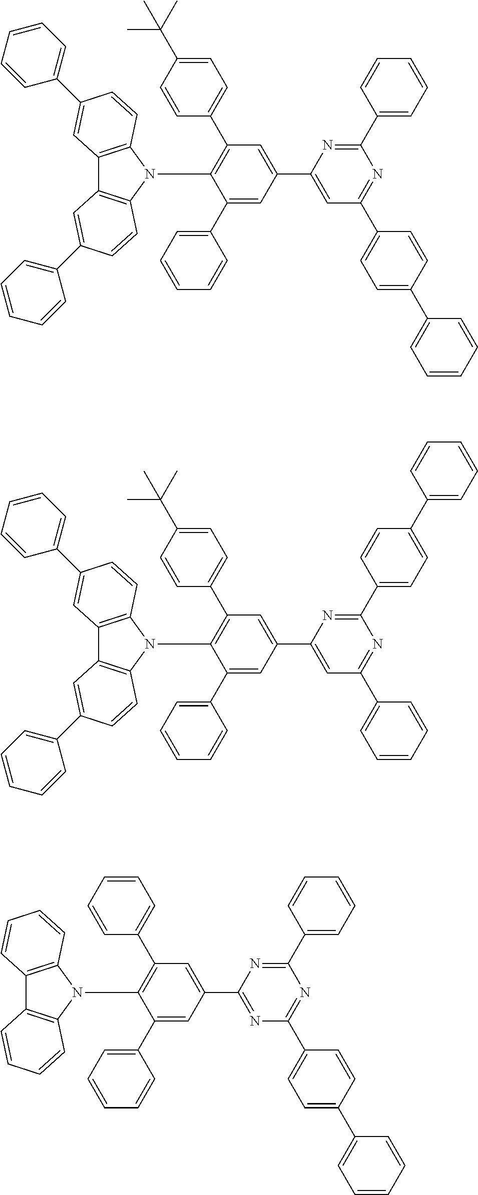 [SMILES: CC(C)(C)c1ccc(-c2cc(-c3cc(-c4ccc(-c5ccccc5)cc4)nc(-c4ccccc4)n3)cc(-c3ccccc3)c2-n2c3ccc(-c4ccccc4)cc3c3cc(-c4ccccc4)ccc32)cc1 ; CC(C)(C)c1ccc(-c2cc(-c3cc(-c4ccccc4)nc(-c4ccc(-c5ccccc5)cc4)n3)cc(-c3ccccc3)c2-n2c3ccc(-c4ccccc4)cc3c3cc(-c4ccccc4)ccc32)cc1 ; c1ccc(-c2ccc(-c3nc(-c4ccccc4)nc(-c4cc(-c5ccccc5)c(-n5c6ccccc6c6ccccc65)c(-c5ccccc5)c4)n3)cc2)cc1]

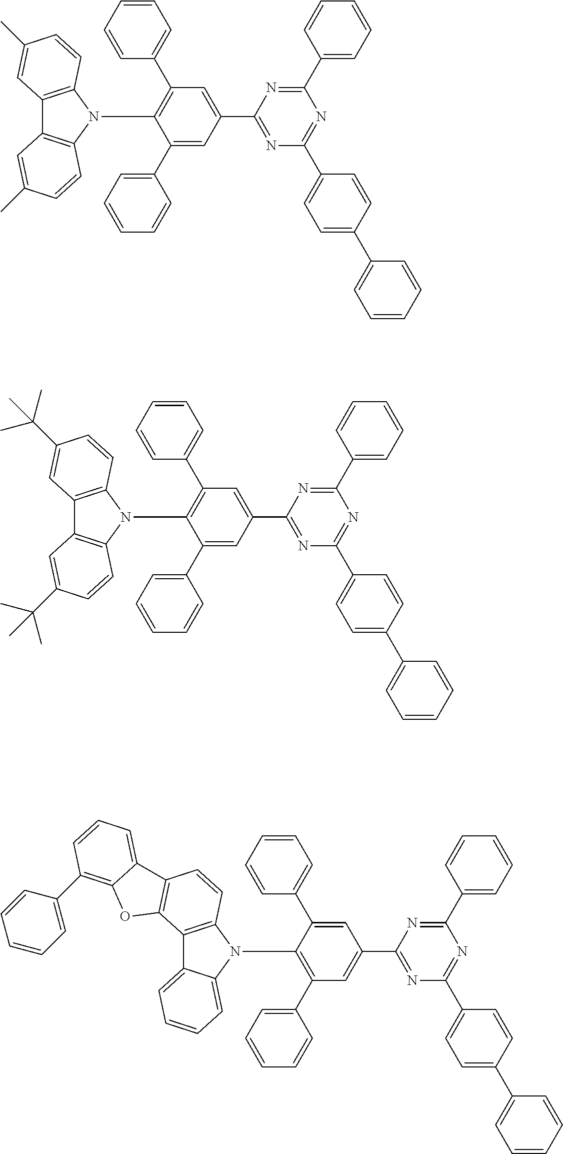 [SMILES: Cc1ccc2c(c1)c1cc(C)ccc1n2-c1c(-c2ccccc2)cc(-c2nc(-c3ccccc3)nc(-c3ccc(-c4ccccc4)cc3)n2)cc1-c1ccccc1 ; CC(C)(C)c1ccc2c(c1)c1cc(C(C)(C)C)ccc1n2-c1c(-c2ccccc2)cc(-c2nc(-c3ccccc3)nc(-c3ccc(-c4ccccc4)cc3)n2)cc1-c1ccccc1 ; c1ccc(-c2ccc(-c3nc(-c4ccccc4)nc(-c4cc(-c5ccccc5)c(-n5c6ccccc6c6c7oc8c(-c9ccccc9)cccc8c7ccc65)c(-c5ccccc5)c4)n3)cc2)cc1]

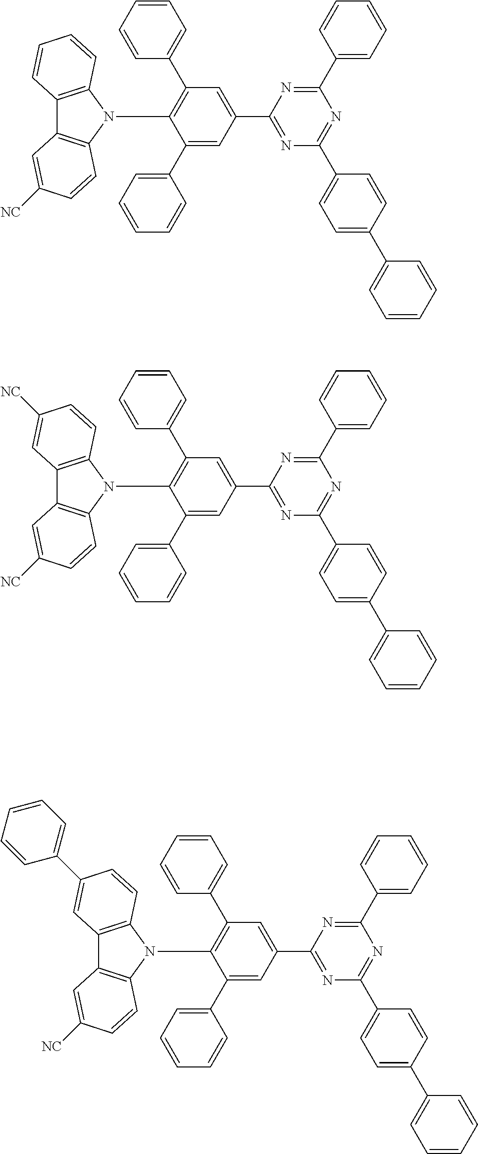 [SMILES: N#Cc1ccc2c(c1)c1ccccc1n2-c1c(-c2ccccc2)cc(-c2nc(-c3ccccc3)nc(-c3ccc(-c4ccccc4)cc3)n2)cc1-c1ccccc1 ; N#Cc1ccc2c(c1)c1cc(C#N)ccc1n2-c1c(-c2ccccc2)cc(-c2nc(-c3ccccc3)nc(-c3ccc(-c4ccccc4)cc3)n2)cc1-c1ccccc1 ; N#Cc1ccc2c(c1)c1cc(-c3ccccc3)ccc1n2-c1c(-c2ccccc2)cc(-c2nc(-c3ccccc3)nc(-c3ccc(-c4ccccc4)cc3)n2)cc1-c1ccccc1]

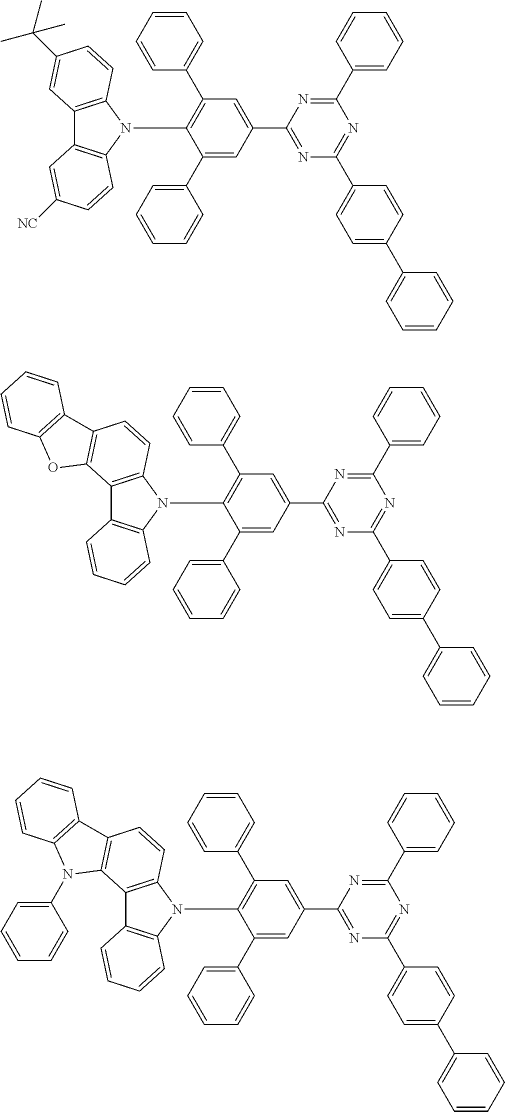 [SMILES: CC(C)(C)c1ccc2c(c1)c1cc(C#N)ccc1n2-c1c(-c2ccccc2)cc(-c2nc(-c3ccccc3)nc(-c3ccc(-c4ccccc4)cc3)n2)cc1-c1ccccc1 ; c1ccc(-c2ccc(-c3nc(-c4ccccc4)nc(-c4cc(-c5ccccc5)c(-n5c6ccccc6c6c7oc8ccccc8c7ccc65)c(-c5ccccc5)c4)n3)cc2)cc1 ; c1ccc(-c2ccc(-c3nc(-c4ccccc4)nc(-c4cc(-c5ccccc5)c(-n5c6ccccc6c6c5ccc5c7ccccc7n(-c7ccccc7)c56)c(-c5ccccc5)c4)n3)cc2)cc1]

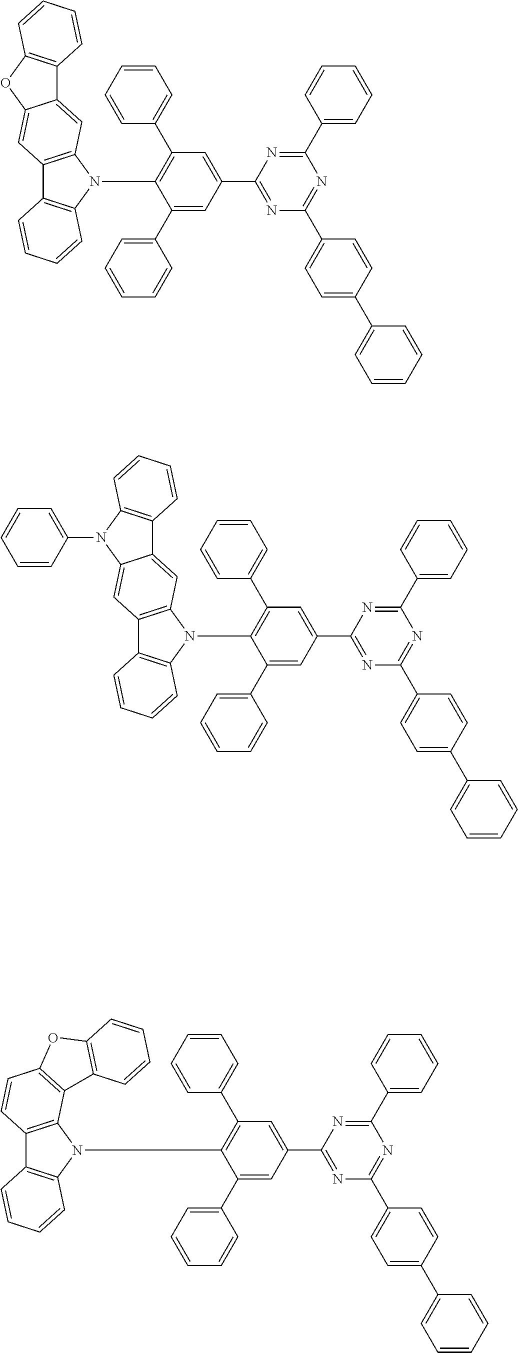 [SMILES: c1ccc(-c2ccc(-c3nc(-c4ccccc4)nc(-c4cc(-c5ccccc5)c(-n5c6ccccc6c6cc7oc8ccccc8c7cc65)c(-c5ccccc5)c4)n3)cc2)cc1 ; c1ccc(-c2ccc(-c3nc(-c4ccccc4)nc(-c4cc(-c5ccccc5)c(-n5c6ccccc6c6cc7c(cc65)c5ccccc5n7-c5ccccc5)c(-c5ccccc5)c4)n3)cc2)cc1 ; c1ccc(-c2ccc(-c3nc(-c4ccccc4)nc(-c4cc(-c5ccccc5)c(-n5c6ccccc6c6ccc7oc8ccccc8c7c65)c(-c5ccccc5)c4)n3)cc2)cc1]

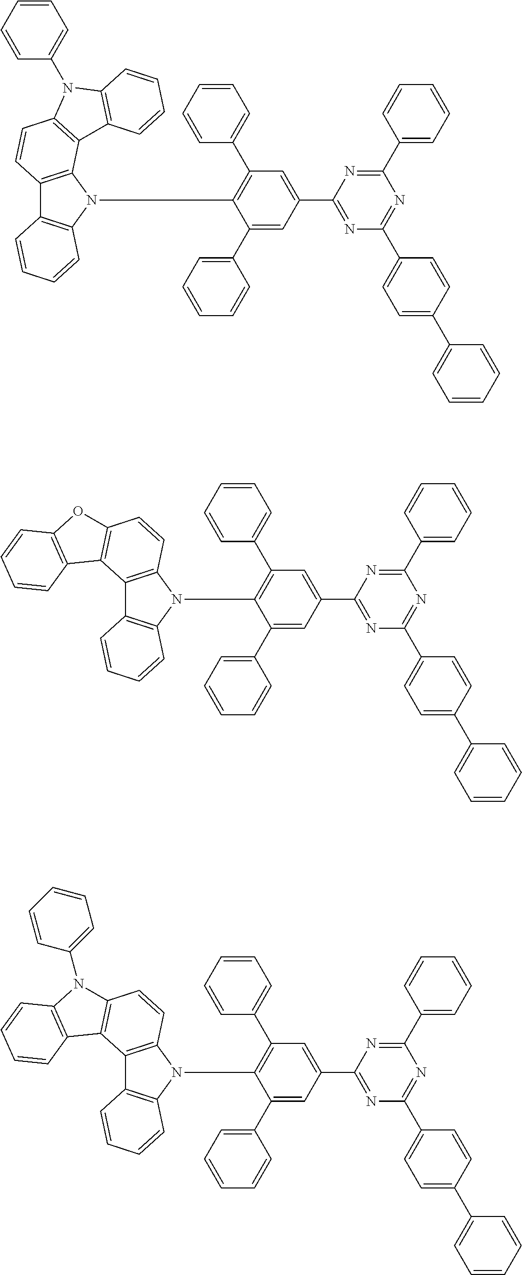 [SMILES: c1ccc(-c2ccc(-c3nc(-c4ccccc4)nc(-c4cc(-c5ccccc5)c(-n5c6ccccc6c6ccc7c(c8ccccc8n7-c7ccccc7)c65)c(-c5ccccc5)c4)n3)cc2)cc1 ; c1ccc(-c2ccc(-c3nc(-c4ccccc4)nc(-c4cc(-c5ccccc5)c(-n5c6ccccc6c6c7c(ccc65)oc5ccccc57)c(-c5ccccc5)c4)n3)cc2)cc1 ; c1ccc(-c2ccc(-c3nc(-c4ccccc4)nc(-c4cc(-c5ccccc5)c(-n5c6ccccc6c6c7c8ccccc8n(-c8ccccc8)c7ccc65)c(-c5ccccc5)c4)n3)cc2)cc1]

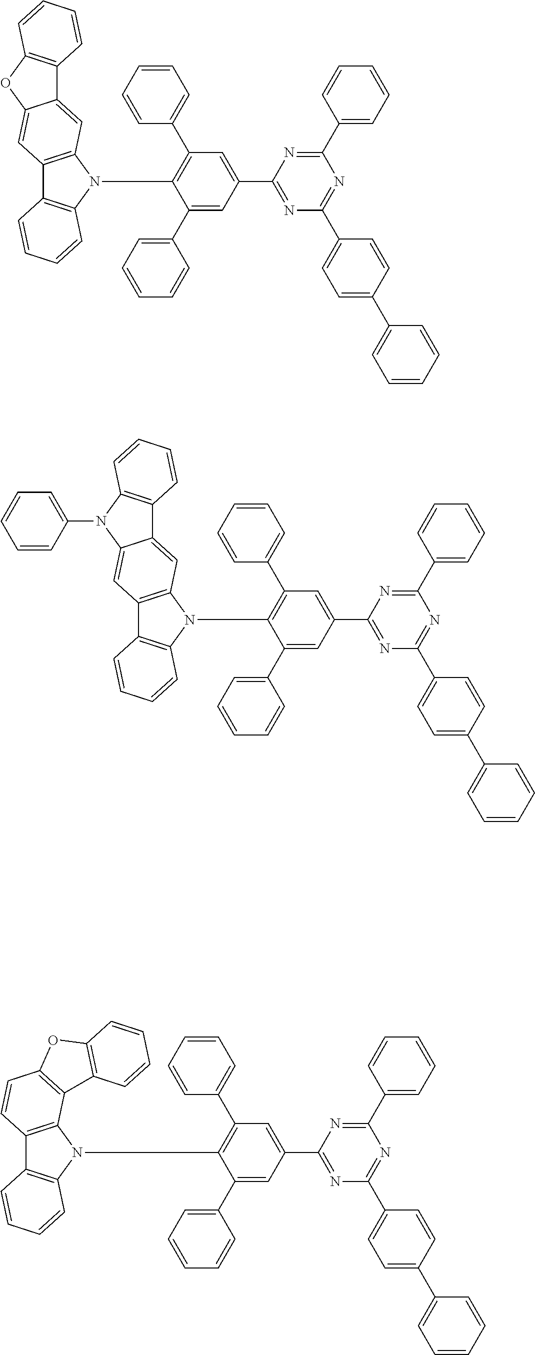 [SMILES: c1ccc(-c2ccc(-c3nc(-c4ccccc4)nc(-c4cc(-c5ccccc5)c(-n5c6ccccc6c6cc7oc8ccccc8c7cc65)c(-c5ccccc5)c4)n3)cc2)cc1 ; c1ccc(-c2ccc(-c3nc(-c4ccccc4)nc(-c4cc(-c5ccccc5)c(-n5c6ccccc6c6cc7c(cc65)c5ccccc5n7-c5ccccc5)c(-c5ccccc5)c4)n3)cc2)cc1 ; c1ccc(-c2ccc(-c3nc(-c4ccccc4)nc(-c4cc(-c5ccccc5)c(-n5c6ccccc6c6ccc7oc8ccccc8c7c65)c(-c5ccccc5)c4)n3)cc2)cc1]

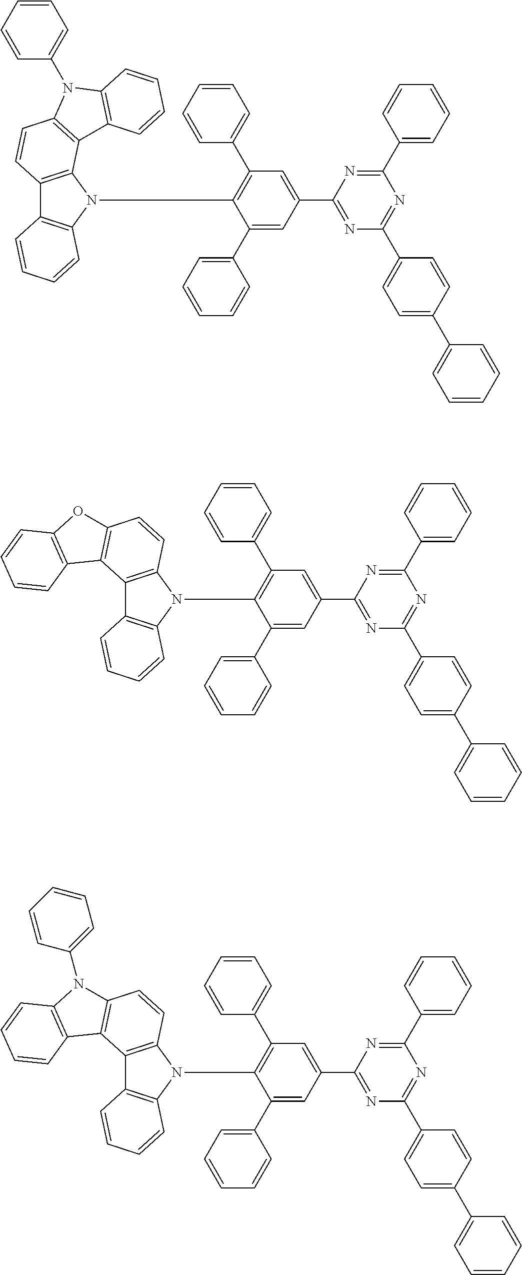 [SMILES: c1ccc(-c2ccc(-c3nc(-c4ccccc4)nc(-c4cc(-c5ccccc5)c(-n5c6ccccc6c6ccc7c(c8ccccc8n7-c7ccccc7)c65)c(-c5ccccc5)c4)n3)cc2)cc1 ; c1ccc(-c2ccc(-c3nc(-c4ccccc4)nc(-c4cc(-c5ccccc5)c(-n5c6ccccc6c6c7c(ccc65)oc5ccccc57)c(-c5ccccc5)c4)n3)cc2)cc1 ; c1ccc(-c2ccc(-c3nc(-c4ccccc4)nc(-c4cc(-c5ccccc5)c(-n5c6ccccc6c6c7c8ccccc8n(-c8ccccc8)c7ccc65)c(-c5ccccc5)c4)n3)cc2)cc1]

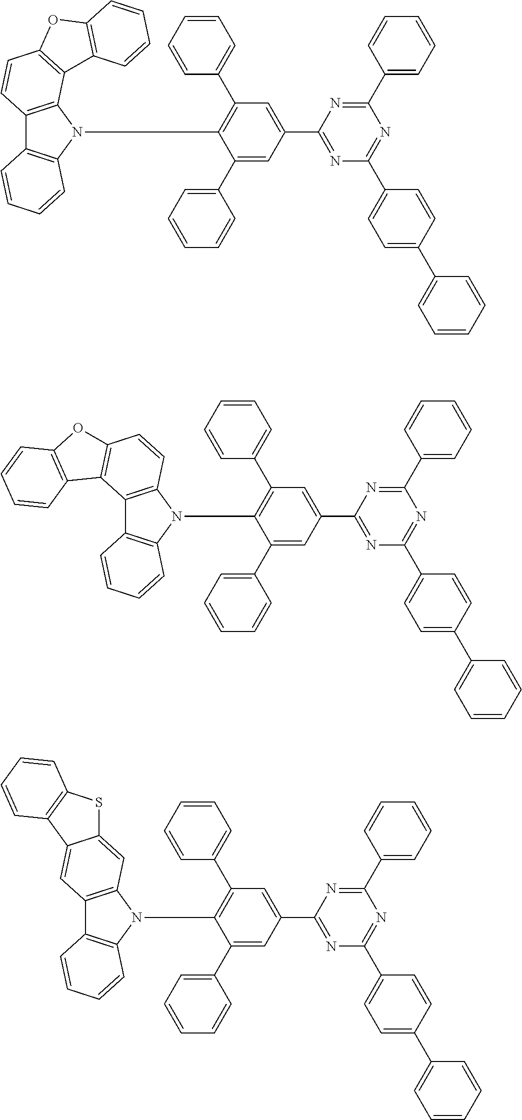 [SMILES: c1ccc(-c2ccc(-c3nc(-c4ccccc4)nc(-c4cc(-c5ccccc5)c(-n5c6ccccc6c6ccc7oc8ccccc8c7c65)c(-c5ccccc5)c4)n3)cc2)cc1 ; c1ccc(-c2ccc(-c3nc(-c4ccccc4)nc(-c4cc(-c5ccccc5)c(-n5c6ccccc6c6c7c(ccc65)oc5ccccc57)c(-c5ccccc5)c4)n3)cc2)cc1 ; c1ccc(-c2ccc(-c3nc(-c4ccccc4)nc(-c4cc(-c5ccccc5)c(-n5c6ccccc6c6cc7c(cc65)sc5ccccc57)c(-c5ccccc5)c4)n3)cc2)cc1]

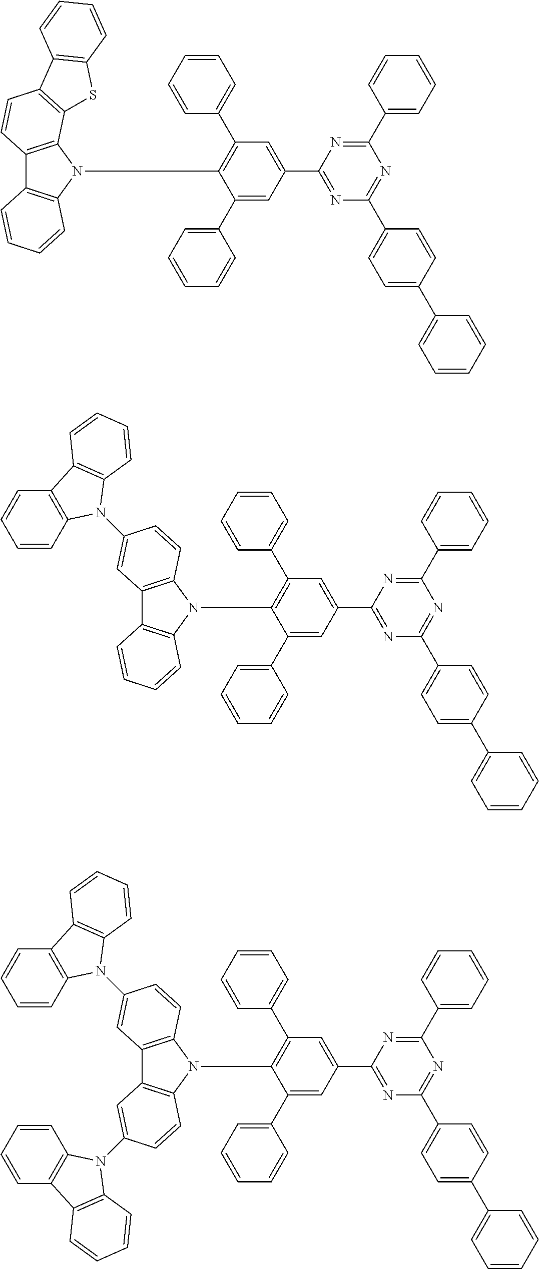 [SMILES: c1ccc(-c2ccc(-c3nc(-c4ccccc4)nc(-c4cc(-c5ccccc5)c(-n5c6ccccc6c6ccc7c8ccccc8sc7c65)c(-c5ccccc5)c4)n3)cc2)cc1 ; c1ccc(-c2ccc(-c3nc(-c4ccccc4)nc(-c4cc(-c5ccccc5)c(-n5c6ccccc6c6cc(-n7c8ccccc8c8ccccc87)ccc65)c(-c5ccccc5)c4)n3)cc2)cc1 ; c1ccc(-c2ccc(-c3nc(-c4ccccc4)nc(-c4cc(-c5ccccc5)c(-n5c6ccc(-n7c8ccccc8c8ccccc87)cc6c6cc(-n7c8ccccc8c8ccccc87)ccc65)c(-c5ccccc5)c4)n3)cc2)cc1]

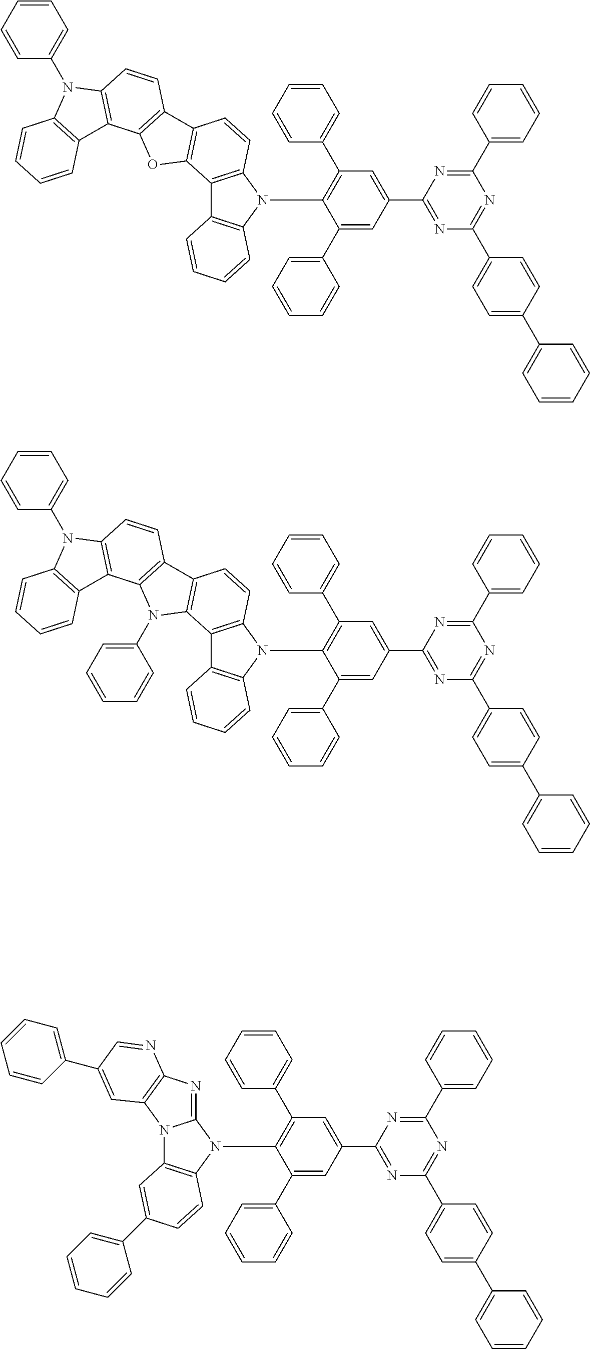 [SMILES: c1ccc(-c2ccc(-c3nc(-c4ccccc4)nc(-c4cc(-c5ccccc5)c(-n5c6ccccc6c6c7oc8c(ccc9c8c8ccccc8n9-c8ccccc8)c7ccc65)c(-c5ccccc5)c4)n3)cc2)cc1 ; c1ccc(-c2ccc(-c3nc(-c4ccccc4)nc(-c4cc(-c5ccccc5)c(-n5c6ccccc6c6c5ccc5c7ccc8c(c9ccccc9n8-c8ccccc8)c7n(-c7ccccc7)c56)c(-c5ccccc5)c4)n3)cc2)cc1 ; c1ccc(-c2ccc(-c3nc(-c4ccccc4)nc(-c4cc(-c5ccccc5)c(-n5c6ccc(-c7ccccc7)cc6n6c7cc(-c8ccccc8)cnc7nc56)c(-c5ccccc5)c4)n3)cc2)cc1]

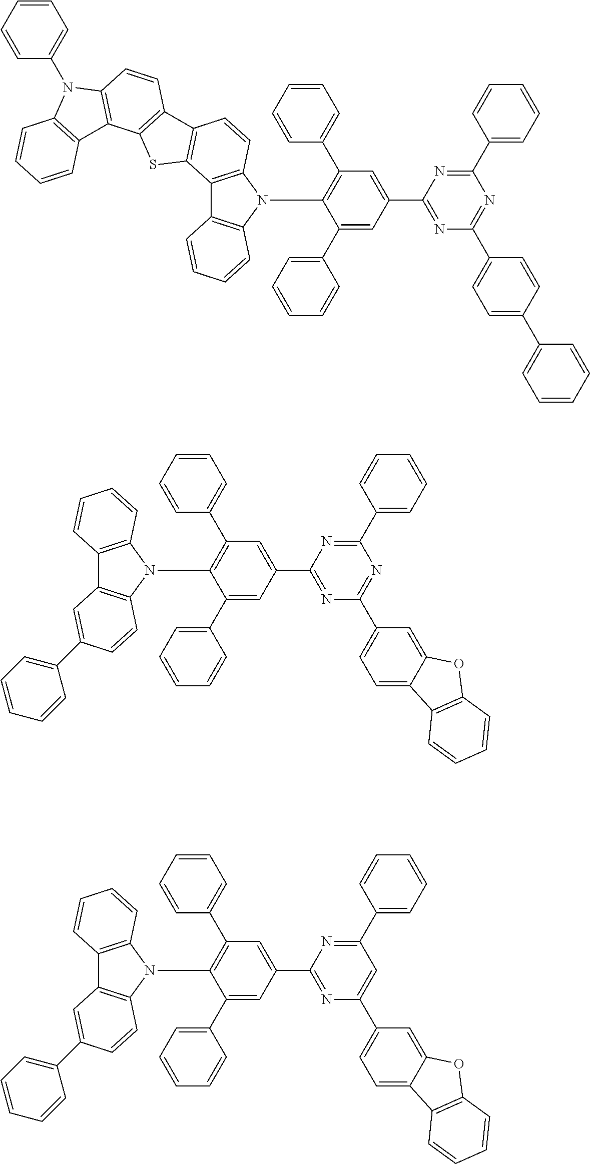 [SMILES: c1ccc(-c2ccc(-c3nc(-c4ccccc4)nc(-c4cc(-c5ccccc5)c(-n5c6ccccc6c6c7sc8c(ccc9c8c8ccccc8n9-c8ccccc8)c7ccc65)c(-c5ccccc5)c4)n3)cc2)cc1 ; c1ccc(-c2ccc3c(c2)c2ccccc2n3-c2c(-c3ccccc3)cc(-c3nc(-c4ccccc4)nc(-c4ccc5c(c4)oc4ccccc45)n3)cc2-c2ccccc2)cc1 ; c1ccc(-c2ccc3c(c2)c2ccccc2n3-c2c(-c3ccccc3)cc(-c3nc(-c4ccccc4)cc(-c4ccc5c(c4)oc4ccccc45)n3)cc2-c2ccccc2)cc1]

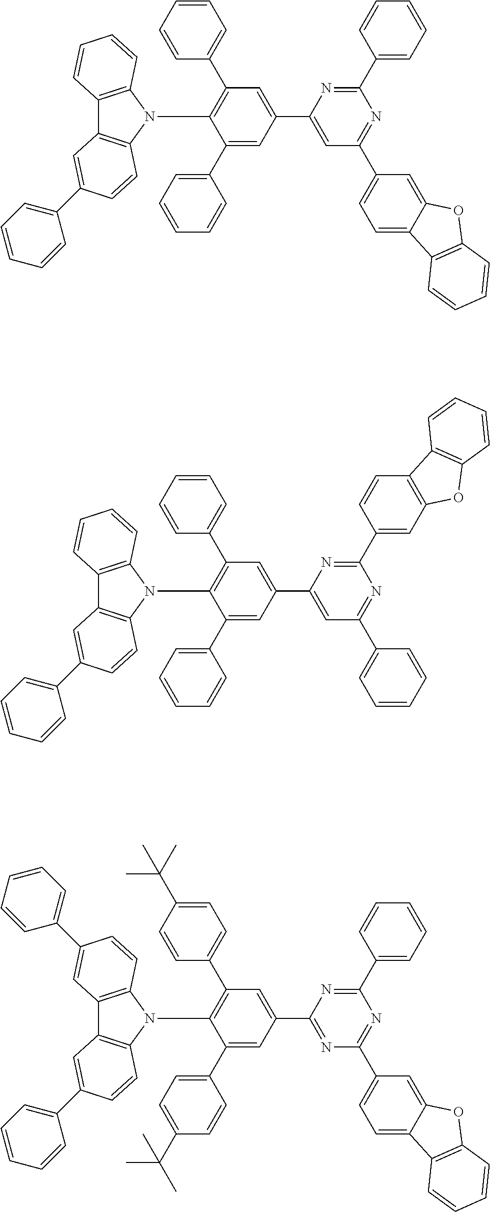 [SMILES: c1ccc(-c2ccc3c(c2)c2ccccc2n3-c2c(-c3ccccc3)cc(-c3cc(-c4ccc5c(c4)oc4ccccc45)nc(-c4ccccc4)n3)cc2-c2ccccc2)cc1 ; c1ccc(-c2ccc3c(c2)c2ccccc2n3-c2c(-c3ccccc3)cc(-c3cc(-c4ccccc4)nc(-c4ccc5c(c4)oc4ccccc45)n3)cc2-c2ccccc2)cc1 ; CC(C)(C)c1ccc(-c2cc(-c3nc(-c4ccccc4)nc(-c4ccc5c(c4)oc4ccccc45)n3)cc(-c3ccc(C(C)(C)C)cc3)c2-n2c3ccc(-c4ccccc4)cc3c3cc(-c4ccccc4)ccc32)cc1]

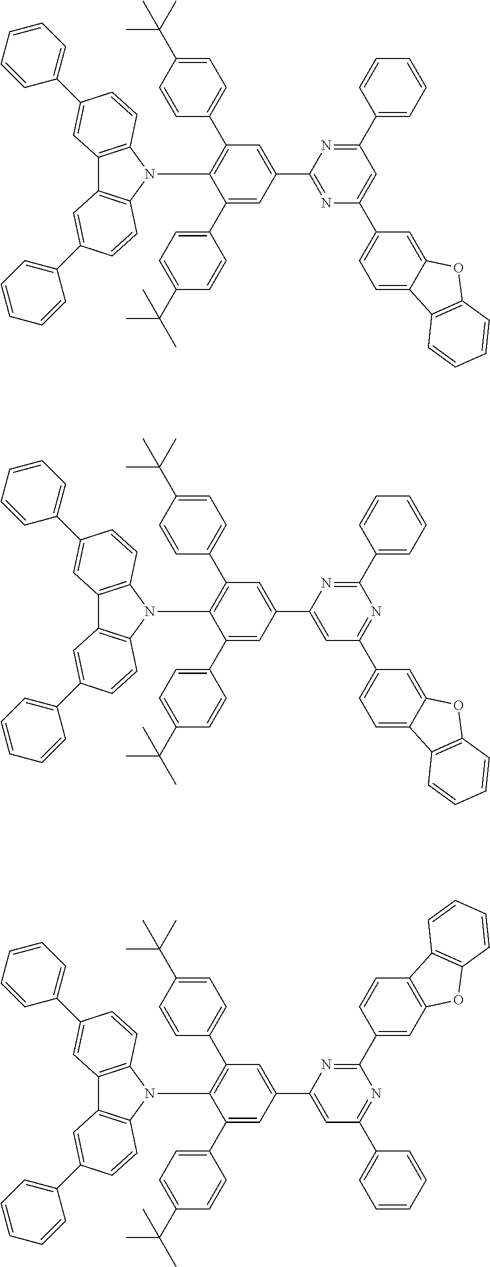 [SMILES: CC(C)(C)c1ccc(-c2cc(-c3nc(-c4ccccc4)cc(-c4ccc5c(c4)oc4ccccc45)n3)cc(-c3ccc(C(C)(C)C)cc3)c2-n2c3ccc(-c4ccccc4)cc3c3cc(-c4ccccc4)ccc32)cc1 ; CC(C)(C)c1ccc(-c2cc(-c3cc(-c4ccc5c(c4)oc4ccccc45)nc(-c4ccccc4)n3)cc(-c3ccc(C(C)(C)C)cc3)c2-n2c3ccc(-c4ccccc4)cc3c3cc(-c4ccccc4)ccc32)cc1 ; CC(C)(C)c1ccc(-c2cc(-c3cc(-c4ccccc4)nc(-c4ccc5c(c4)oc4ccccc45)n3)cc(-c3ccc(C(C)(C)C)cc3)c2-n2c3ccc(-c4ccccc4)cc3c3cc(-c4ccccc4)ccc32)cc1]

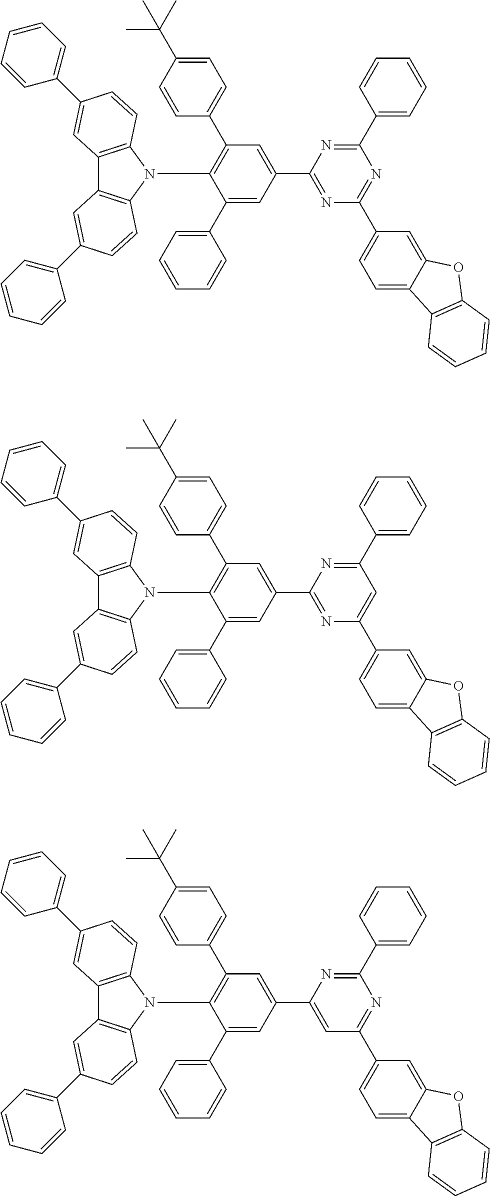 [SMILES: CC(C)(C)c1ccc(-c2cc(-c3nc(-c4ccccc4)nc(-c4ccc5c(c4)oc4ccccc45)n3)cc(-c3ccccc3)c2-n2c3ccc(-c4ccccc4)cc3c3cc(-c4ccccc4)ccc32)cc1 ; CC(C)(C)c1ccc(-c2cc(-c3nc(-c4ccccc4)cc(-c4ccc5c(c4)oc4ccccc45)n3)cc(-c3ccccc3)c2-n2c3ccc(-c4ccccc4)cc3c3cc(-c4ccccc4)ccc32)cc1 ; CC(C)(C)c1ccc(-c2cc(-c3cc(-c4ccc5c(c4)oc4ccccc45)nc(-c4ccccc4)n3)cc(-c3ccccc3)c2-n2c3ccc(-c4ccccc4)cc3c3cc(-c4ccccc4)ccc32)cc1]

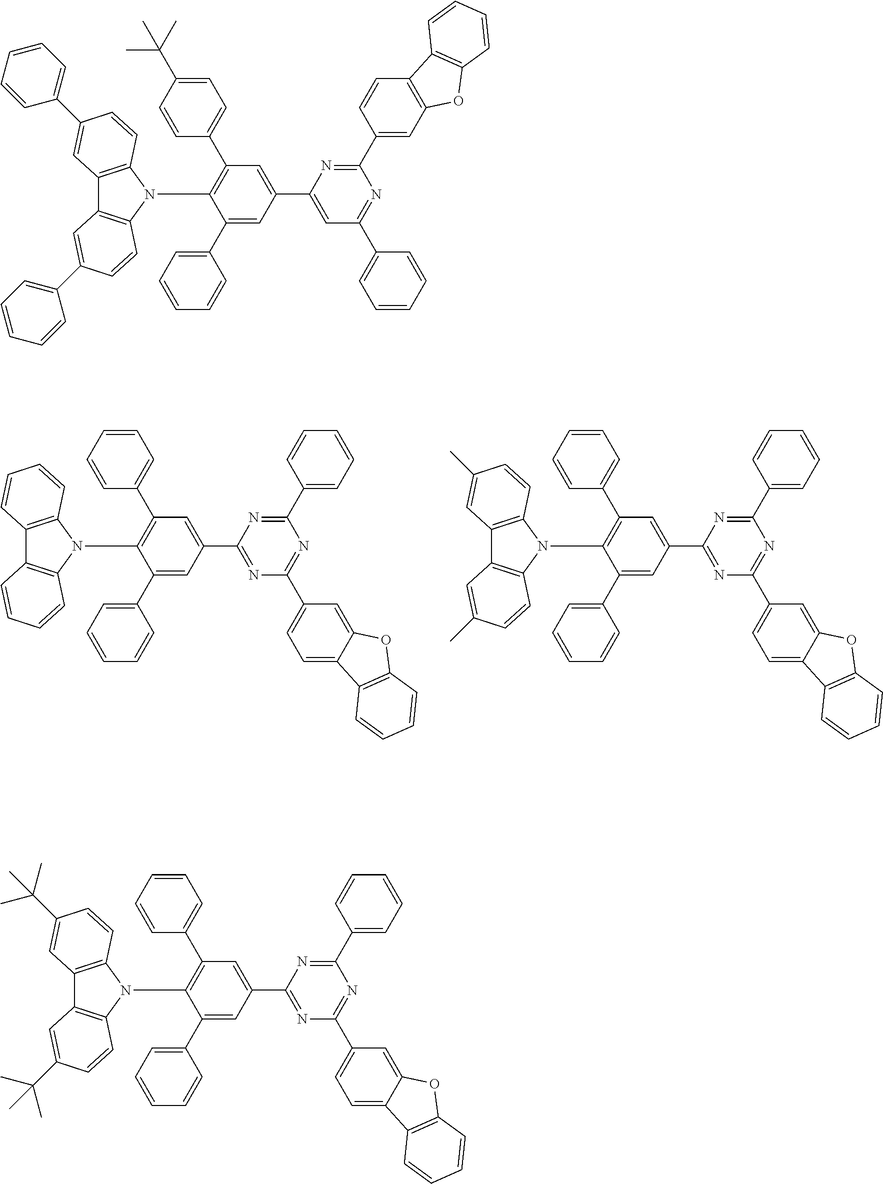 [SMILES: CC(C)(C)c1ccc(-c2cc(-c3cc(-c4ccccc4)nc(-c4ccc5c(c4)oc4ccccc45)n3)cc(-c3ccccc3)c2-n2c3ccc(-c4ccccc4)cc3c3cc(-c4ccccc4)ccc32)cc1 ; c1ccc(-c2nc(-c3cc(-c4ccccc4)c(-n4c5ccccc5c5ccccc54)c(-c4ccccc4)c3)nc(-c3ccc4c(c3)oc3ccccc34)n2)cc1 ; Cc1ccc2c(c1)c1cc(C)ccc1n2-c1c(-c2ccccc2)cc(-c2nc(-c3ccccc3)nc(-c3ccc4c(c3)oc3ccccc34)n2)cc1-c1ccccc1 ; CC(C)(C)c1ccc2c(c1)c1cc(C(C)(C)C)ccc1n2-c1c(-c2ccccc2)cc(-c2nc(-c3ccccc3)nc(-c3ccc4c(c3)oc3ccccc34)n2)cc1-c1ccccc1]

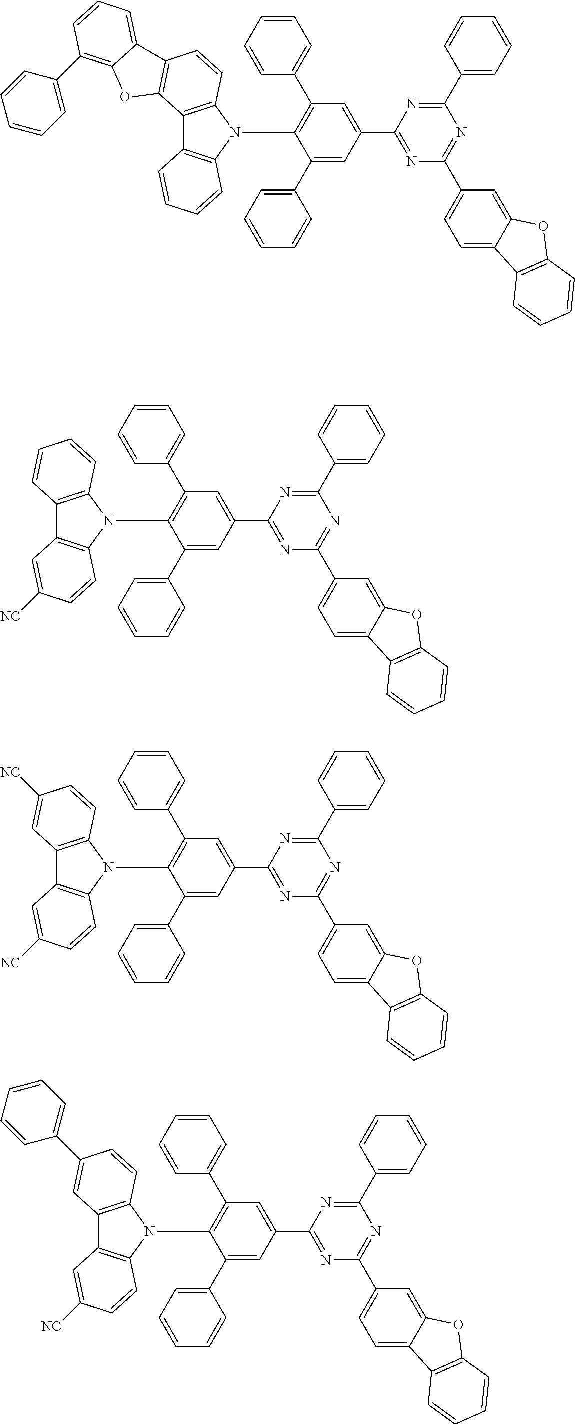 [SMILES: c1ccc(-c2nc(-c3cc(-c4ccccc4)c(-n4c5ccccc5c5c6oc7c(-c8ccccc8)cccc7c6ccc54)c(-c4ccccc4)c3)nc(-c3ccc4c(c3)oc3ccccc34)n2)cc1 ; N#Cc1ccc2c(c1)c1ccccc1n2-c1c(-c2ccccc2)cc(-c2nc(-c3ccccc3)nc(-c3ccc4c(c3)oc3ccccc34)n2)cc1-c1ccccc1 ; N#Cc1ccc2c(c1)c1cc(C#N)ccc1n2-c1c(-c2ccccc2)cc(-c2nc(-c3ccccc3)nc(-c3ccc4c(c3)oc3ccccc34)n2)cc1-c1ccccc1 ; N#Cc1ccc2c(c1)c1cc(-c3ccccc3)ccc1n2-c1c(-c2ccccc2)cc(-c2nc(-c3ccccc3)nc(-c3ccc4c(c3)oc3ccccc34)n2)cc1-c1ccccc1]

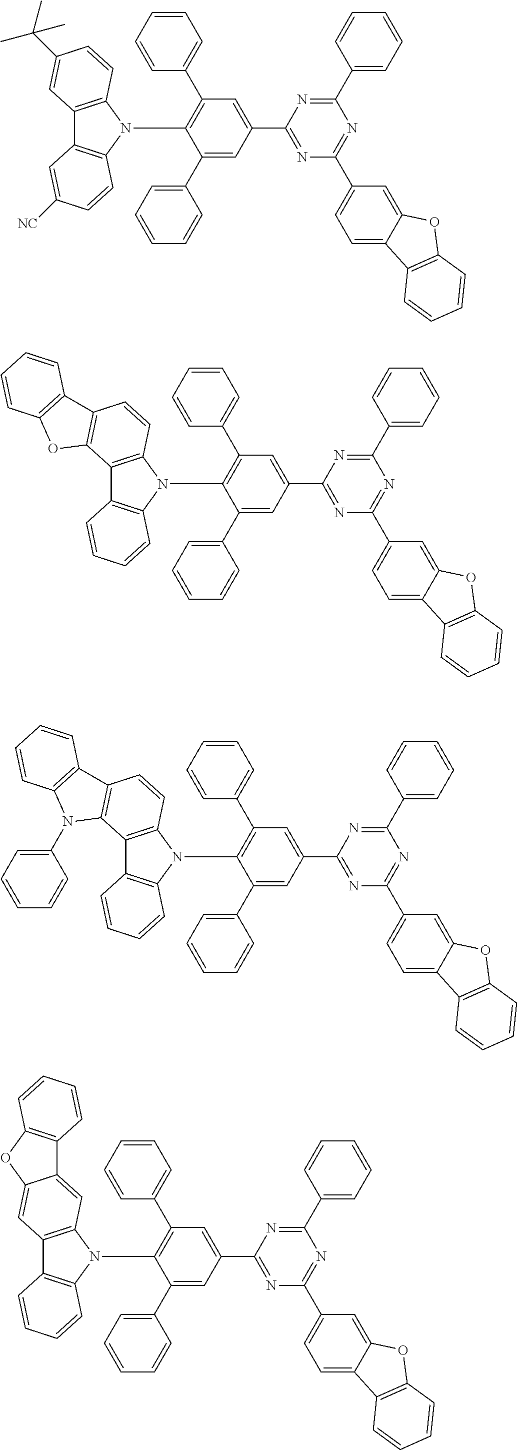 [SMILES: CC(C)(C)c1ccc2c(c1)c1cc(C#N)ccc1n2-c1c(-c2ccccc2)cc(-c2nc(-c3ccccc3)nc(-c3ccc4c(c3)oc3ccccc34)n2)cc1-c1ccccc1 ; c1ccc(-c2nc(-c3cc(-c4ccccc4)c(-n4c5ccccc5c5c6oc7ccccc7c6ccc54)c(-c4ccccc4)c3)nc(-c3ccc4c(c3)oc3ccccc34)n2)cc1 ; c1ccc(-c2nc(-c3cc(-c4ccccc4)c(-n4c5ccccc5c5c4ccc4c6ccccc6n(-c6ccccc6)c45)c(-c4ccccc4)c3)nc(-c3ccc4c(c3)oc3ccccc34)n2)cc1 ; c1ccc(-c2nc(-c3cc(-c4ccccc4)c(-n4c5ccccc5c5cc6oc7ccccc7c6cc54)c(-c4ccccc4)c3)nc(-c3ccc4c(c3)oc3ccccc34)n2)cc1]

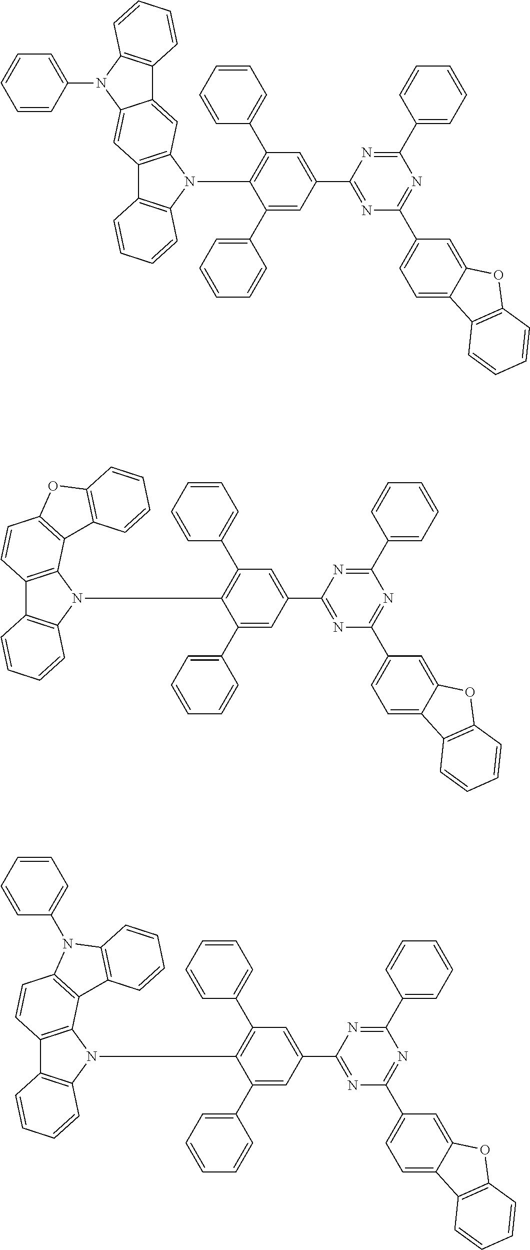 [SMILES: c1ccc(-c2nc(-c3cc(-c4ccccc4)c(-n4c5ccccc5c5cc6c(cc54)c4ccccc4n6-c4ccccc4)c(-c4ccccc4)c3)nc(-c3ccc4c(c3)oc3ccccc34)n2)cc1 ; c1ccc(-c2nc(-c3cc(-c4ccccc4)c(-n4c5ccccc5c5ccc6oc7ccccc7c6c54)c(-c4ccccc4)c3)nc(-c3ccc4c(c3)oc3ccccc34)n2)cc1 ; c1ccc(-c2nc(-c3cc(-c4ccccc4)c(-n4c5ccccc5c5ccc6c(c7ccccc7n6-c6ccccc6)c54)c(-c4ccccc4)c3)nc(-c3ccc4c(c3)oc3ccccc34)n2)cc1]

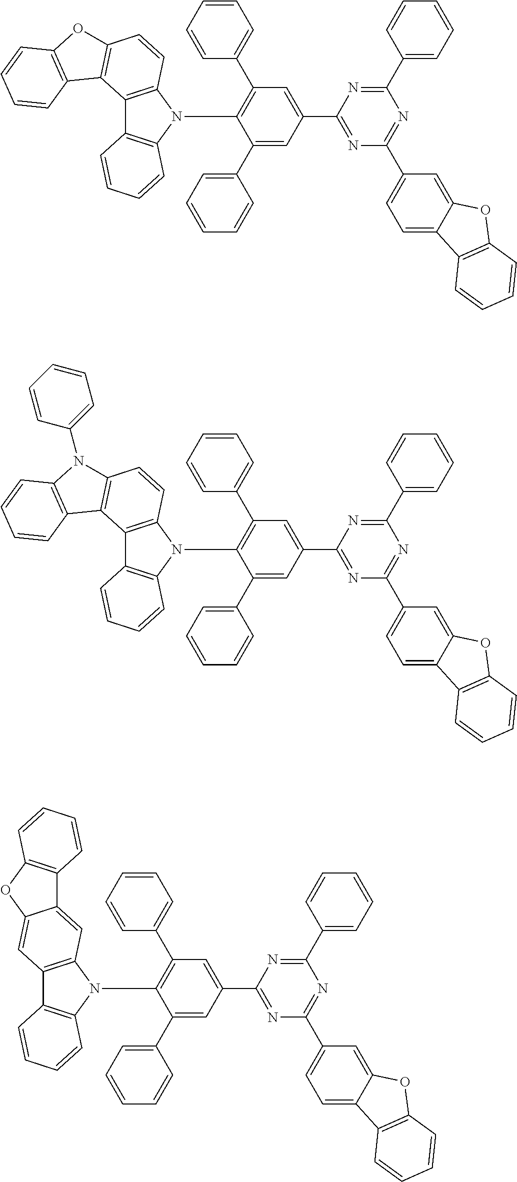 [SMILES: c1ccc(-c2nc(-c3cc(-c4ccccc4)c(-n4c5ccccc5c5c6c(ccc54)oc4ccccc46)c(-c4ccccc4)c3)nc(-c3ccc4c(c3)oc3ccccc34)n2)cc1 ; c1ccc(-c2nc(-c3cc(-c4ccccc4)c(-n4c5ccccc5c5c6c7ccccc7n(-c7ccccc7)c6ccc54)c(-c4ccccc4)c3)nc(-c3ccc4c(c3)oc3ccccc34)n2)cc1 ; c1ccc(-c2nc(-c3cc(-c4ccccc4)c(-n4c5ccccc5c5cc6oc7ccccc7c6cc54)c(-c4ccccc4)c3)nc(-c3ccc4c(c3)oc3ccccc34)n2)cc1]

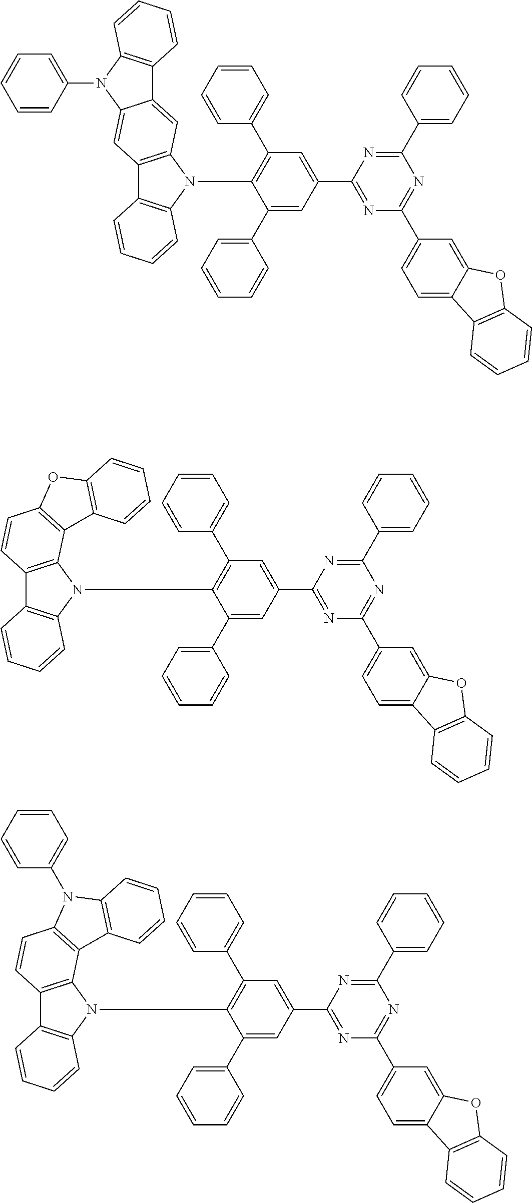 [SMILES: c1ccc(-c2nc(-c3cc(-c4ccccc4)c(-n4c5ccccc5c5cc6c(cc54)c4ccccc4n6-c4ccccc4)c(-c4ccccc4)c3)nc(-c3ccc4c(c3)oc3ccccc34)n2)cc1 ; c1ccc(-c2nc(-c3cc(-c4ccccc4)c(-n4c5ccccc5c5ccc6oc7ccccc7c6c54)c(-c4ccccc4)c3)nc(-c3ccc4c(c3)oc3ccccc34)n2)cc1 ; c1ccc(-c2nc(-c3cc(-c4ccccc4)c(-n4c5ccccc5c5ccc6c(c7ccccc7n6-c6ccccc6)c54)c(-c4ccccc4)c3)nc(-c3ccc4c(c3)oc3ccccc34)n2)cc1]

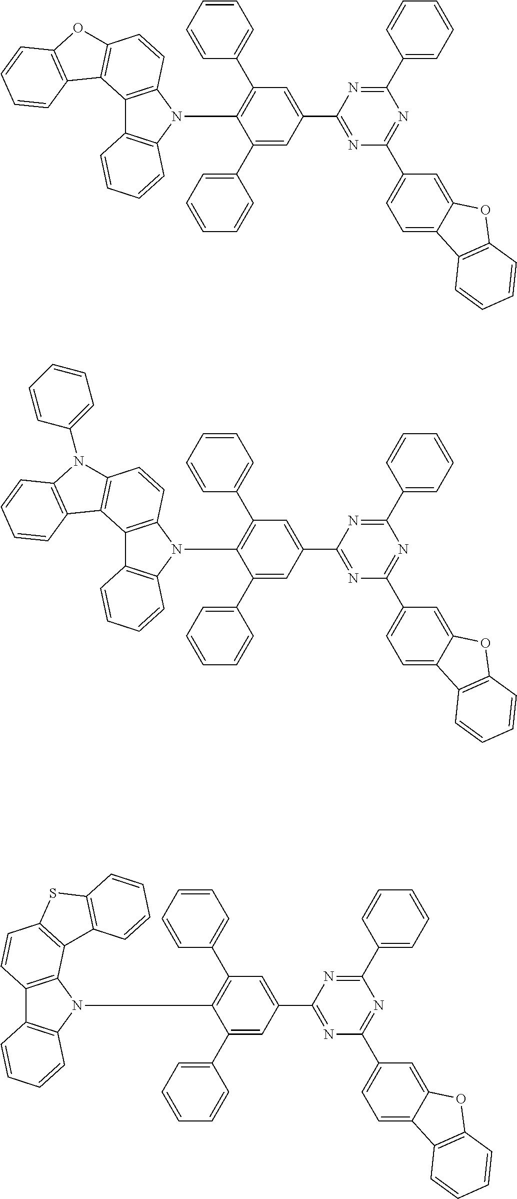 [SMILES: c1ccc(-c2nc(-c3cc(-c4ccccc4)c(-n4c5ccccc5c5c6c(ccc54)oc4ccccc46)c(-c4ccccc4)c3)nc(-c3ccc4c(c3)oc3ccccc34)n2)cc1 ; c1ccc(-c2nc(-c3cc(-c4ccccc4)c(-n4c5ccccc5c5c6c7ccccc7n(-c7ccccc7)c6ccc54)c(-c4ccccc4)c3)nc(-c3ccc4c(c3)oc3ccccc34)n2)cc1 ; c1ccc(-c2nc(-c3cc(-c4ccccc4)c(-n4c5ccccc5c5ccc6sc7ccccc7c6c54)c(-c4ccccc4)c3)nc(-c3ccc4c(c3)oc3ccccc34)n2)cc1]

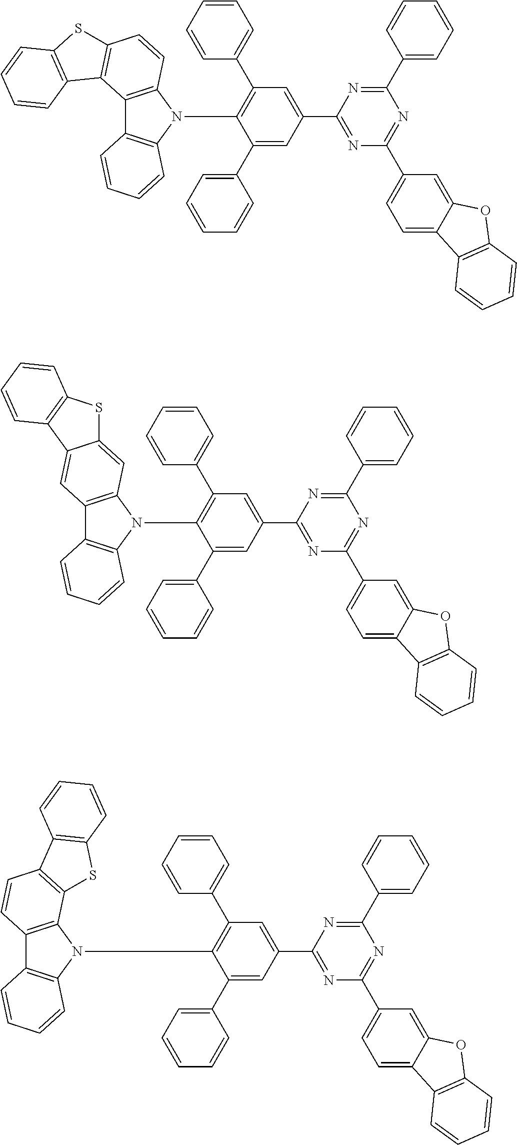 [SMILES: c1ccc(-c2nc(-c3cc(-c4ccccc4)c(-n4c5ccccc5c5c6c(ccc54)sc4ccccc46)c(-c4ccccc4)c3)nc(-c3ccc4c(c3)oc3ccccc34)n2)cc1 ; c1ccc(-c2nc(-c3cc(-c4ccccc4)c(-n4c5ccccc5c5cc6c(cc54)sc4ccccc46)c(-c4ccccc4)c3)nc(-c3ccc4c(c3)oc3ccccc34)n2)cc1 ; c1ccc(-c2nc(-c3cc(-c4ccccc4)c(-n4c5ccccc5c5ccc6c7ccccc7sc6c54)c(-c4ccccc4)c3)nc(-c3ccc4c(c3)oc3ccccc34)n2)cc1]

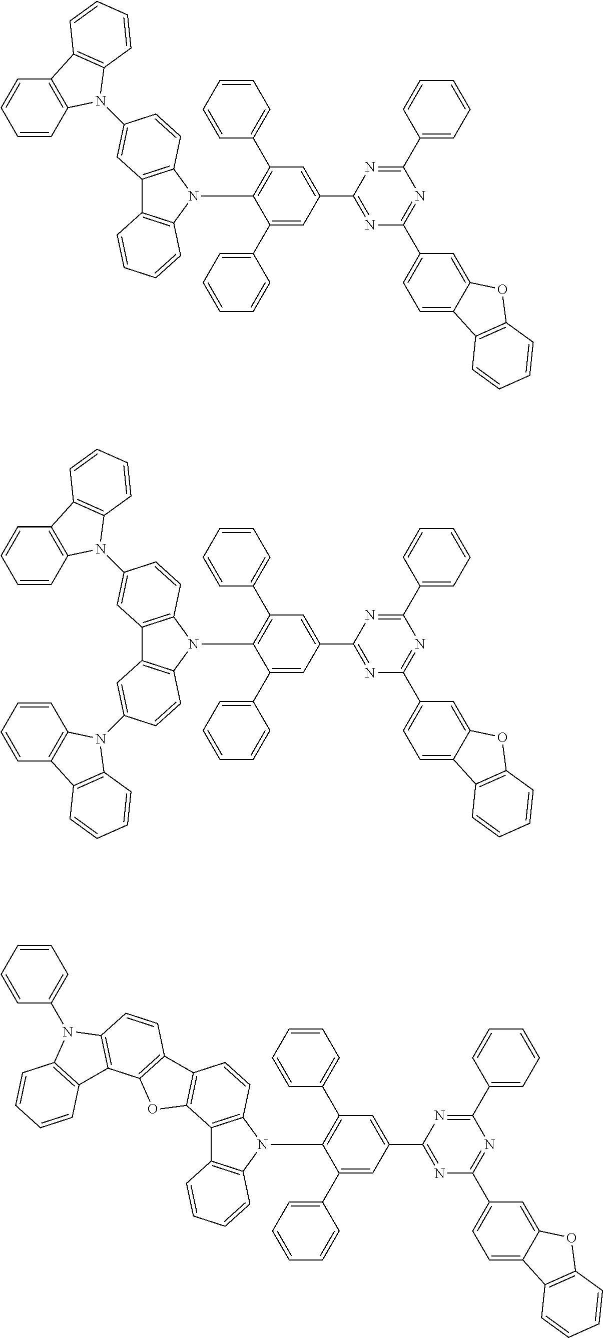 [SMILES: c1ccc(-c2nc(-c3cc(-c4ccccc4)c(-n4c5ccccc5c5cc(-n6c7ccccc7c7ccccc76)ccc54)c(-c4ccccc4)c3)nc(-c3ccc4c(c3)oc3ccccc34)n2)cc1 ; c1ccc(-c2nc(-c3cc(-c4ccccc4)c(-n4c5ccc(-n6c7ccccc7c7ccccc76)cc5c5cc(-n6c7ccccc7c7ccccc76)ccc54)c(-c4ccccc4)c3)nc(-c3ccc4c(c3)oc3ccccc34)n2)cc1 ; c1ccc(-c2nc(-c3cc(-c4ccccc4)c(-n4c5ccccc5c5c6oc7c(ccc8c7c7ccccc7n8-c7ccccc7)c6ccc54)c(-c4ccccc4)c3)nc(-c3ccc4c(c3)oc3ccccc34)n2)cc1]

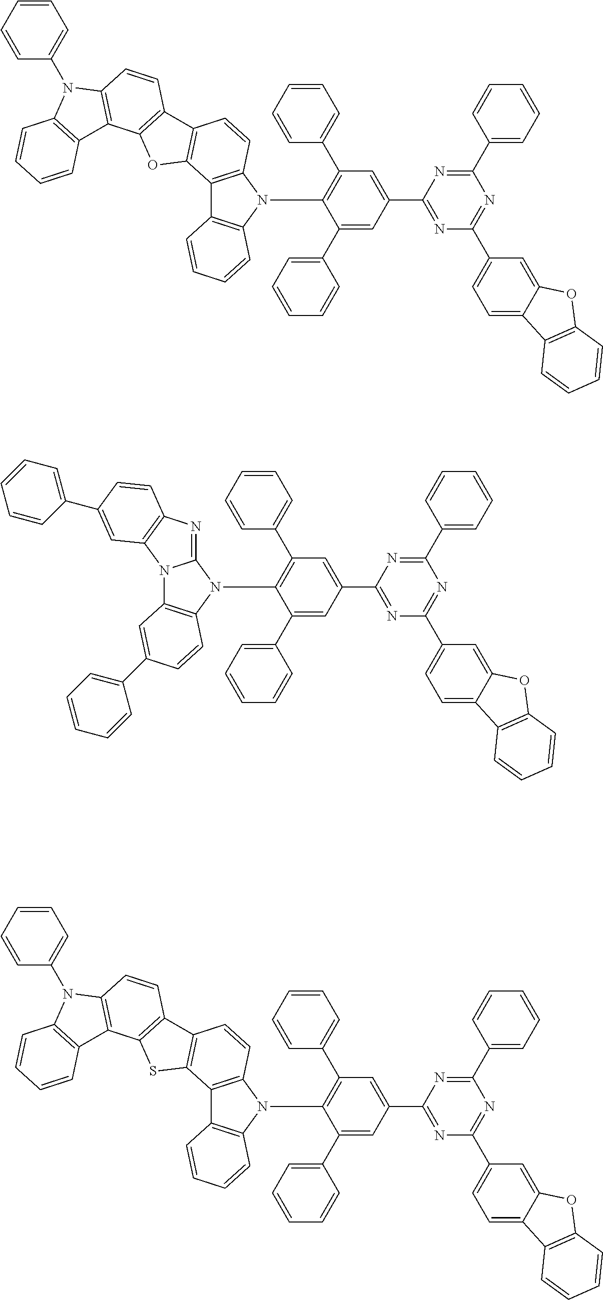 [SMILES: c1ccc(-c2nc(-c3cc(-c4ccccc4)c(-n4c5ccccc5c5c6oc7c(ccc8c7c7ccccc7n8-c7ccccc7)c6ccc54)c(-c4ccccc4)c3)nc(-c3ccc4c(c3)oc3ccccc34)n2)cc1 ; c1ccc(-c2ccc3nc4n(-c5c(-c6ccccc6)cc(-c6nc(-c7ccccc7)nc(-c7ccc8c(c7)oc7ccccc78)n6)cc5-c5ccccc5)c5ccc(-c6ccccc6)cc5n4c3c2)cc1 ; c1ccc(-c2nc(-c3cc(-c4ccccc4)c(-n4c5ccccc5c5c6sc7c(ccc8c7c7ccccc7n8-c7ccccc7)c6ccc54)c(-c4ccccc4)c3)nc(-c3ccc4c(c3)oc3ccccc34)n2)cc1]

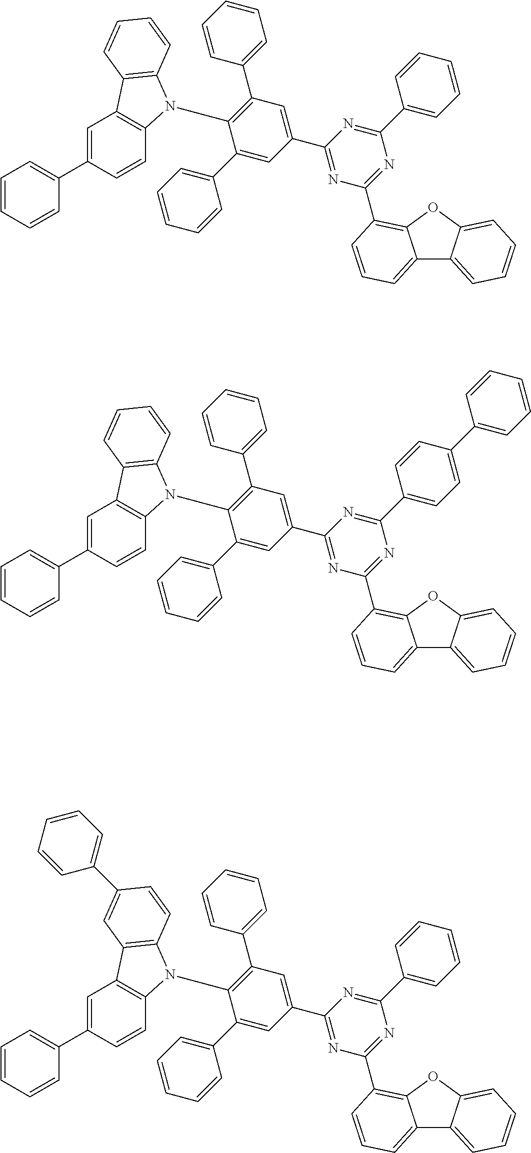 [SMILES: c1ccc(-c2ccc3c(c2)c2ccccc2n3-c2c(-c3ccccc3)cc(-c3nc(-c4ccccc4)nc(-c4cccc5c4oc4ccccc45)n3)cc2-c2ccccc2)cc1 ; c1ccc(-c2ccc(-c3nc(-c4cc(-c5ccccc5)c(-n5c6ccccc6c6cc(-c7ccccc7)ccc65)c(-c5ccccc5)c4)nc(-c4cccc5c4oc4ccccc45)n3)cc2)cc1 ; c1ccc(-c2ccc3c(c2)c2cc(-c4ccccc4)ccc2n3-c2c(-c3ccccc3)cc(-c3nc(-c4ccccc4)nc(-c4cccc5c4oc4ccccc45)n3)cc2-c2ccccc2)cc1]

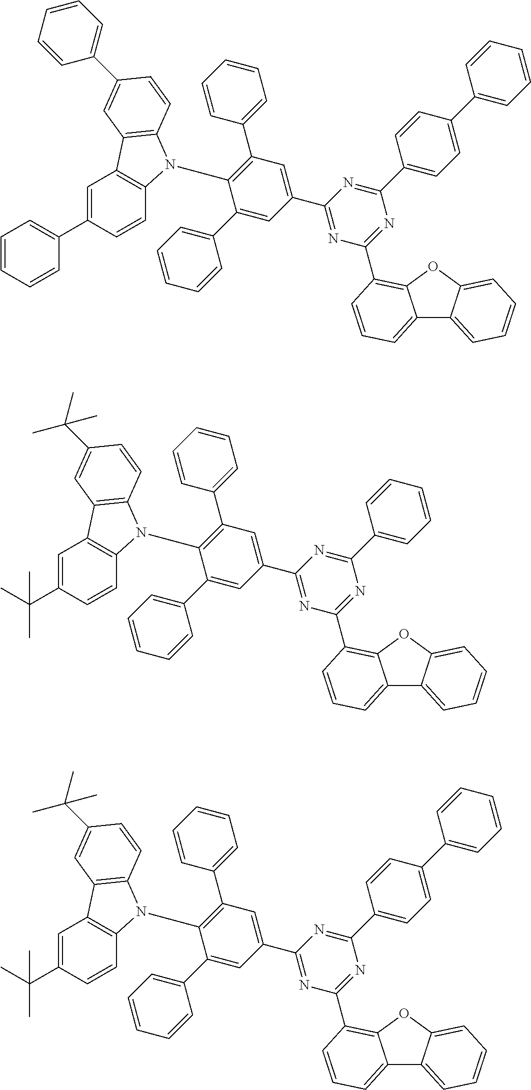 [SMILES: c1ccc(-c2ccc(-c3nc(-c4cc(-c5ccccc5)c(-n5c6ccc(-c7ccccc7)cc6c6cc(-c7ccccc7)ccc65)c(-c5ccccc5)c4)nc(-c4cccc5c4oc4ccccc45)n3)cc2)cc1 ; CC(C)(C)c1ccc2c(c1)c1cc(C(C)(C)C)ccc1n2-c1c(-c2ccccc2)cc(-c2nc(-c3ccccc3)nc(-c3cccc4c3oc3ccccc34)n2)cc1-c1ccccc1 ; CC(C)(C)c1ccc2c(c1)c1cc(C(C)(C)C)ccc1n2-c1c(-c2ccccc2)cc(-c2nc(-c3ccc(-c4ccccc4)cc3)nc(-c3cccc4c3oc3ccccc34)n2)cc1-c1ccccc1]

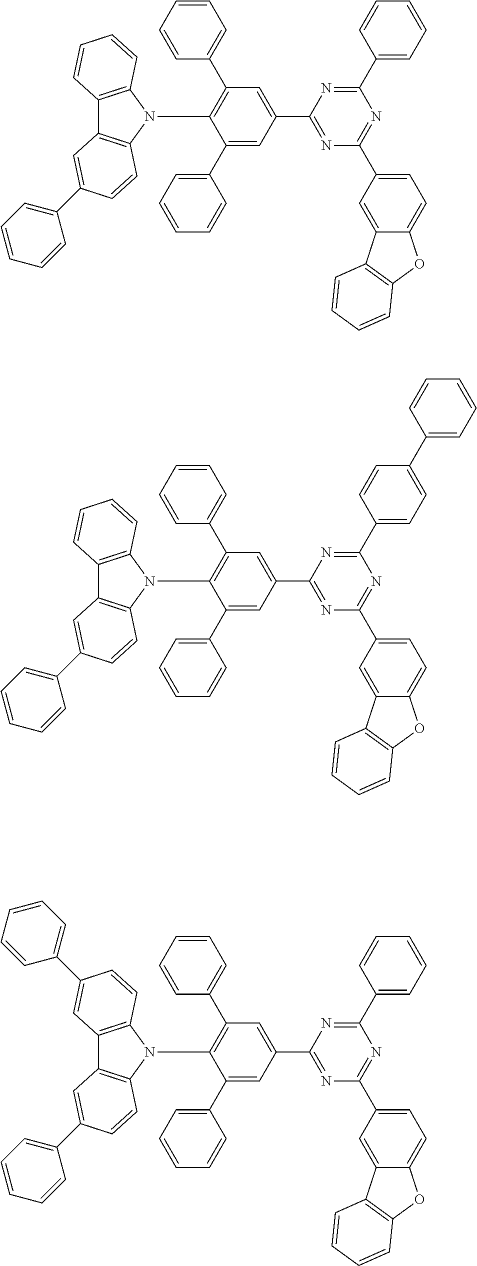 [SMILES: c1ccc(-c2ccc3c(c2)c2ccccc2n3-c2c(-c3ccccc3)cc(-c3nc(-c4ccccc4)nc(-c4ccc5oc6ccccc6c5c4)n3)cc2-c2ccccc2)cc1 ; c1ccc(-c2ccc(-c3nc(-c4cc(-c5ccccc5)c(-n5c6ccccc6c6cc(-c7ccccc7)ccc65)c(-c5ccccc5)c4)nc(-c4ccc5oc6ccccc6c5c4)n3)cc2)cc1 ; c1ccc(-c2ccc3c(c2)c2cc(-c4ccccc4)ccc2n3-c2c(-c3ccccc3)cc(-c3nc(-c4ccccc4)nc(-c4ccc5oc6ccccc6c5c4)n3)cc2-c2ccccc2)cc1]

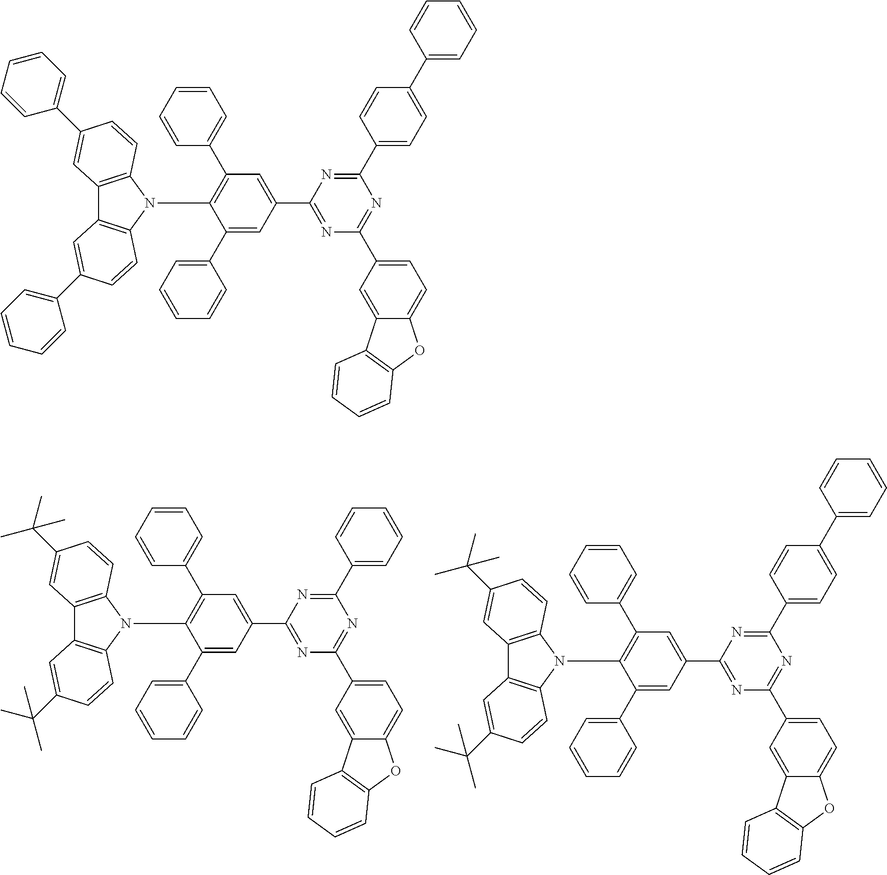

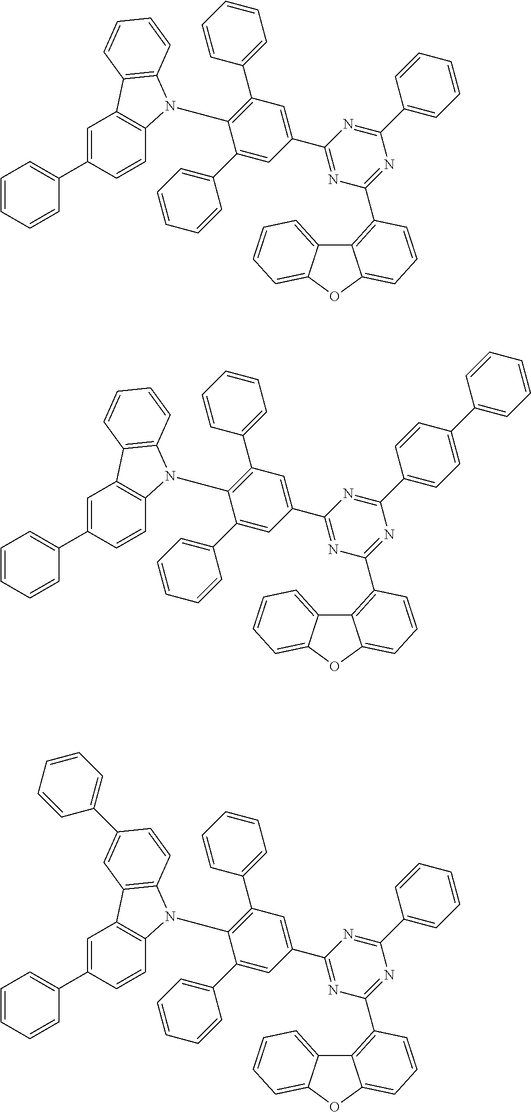 [SMILES: c1ccc(-c2ccc3c(c2)c2ccccc2n3-c2c(-c3ccccc3)cc(-c3nc(-c4ccccc4)nc(-c4cccc5oc6ccccc6c45)n3)cc2-c2ccccc2)cc1 ; c1ccc(-c2ccc(-c3nc(-c4cc(-c5ccccc5)c(-n5c6ccccc6c6cc(-c7ccccc7)ccc65)c(-c5ccccc5)c4)nc(-c4cccc5oc6ccccc6c45)n3)cc2)cc1 ; c1ccc(-c2ccc3c(c2)c2cc(-c4ccccc4)ccc2n3-c2c(-c3ccccc3)cc(-c3nc(-c4ccccc4)nc(-c4cccc5oc6ccccc6c45)n3)cc2-c2ccccc2)cc1]

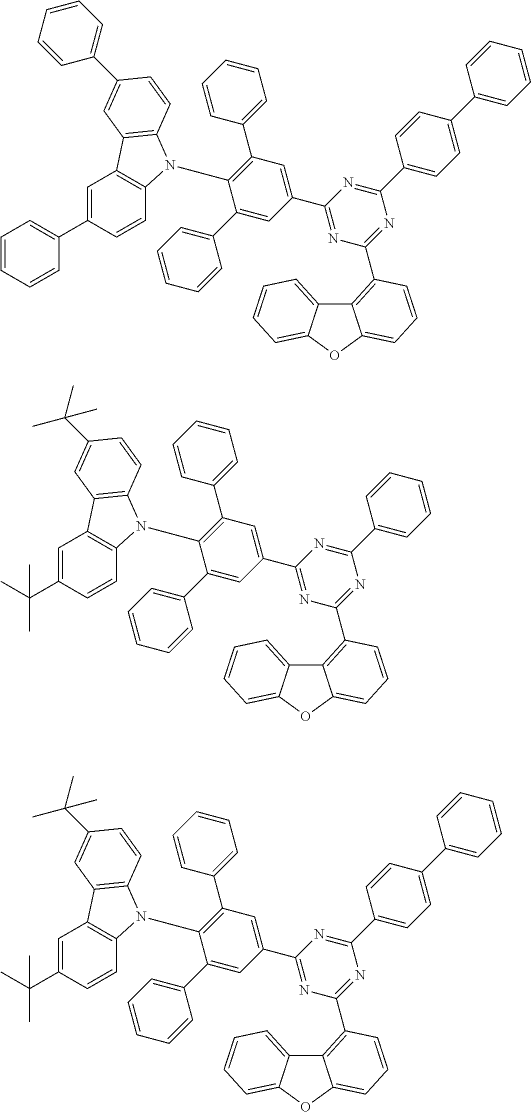 [SMILES: c1ccc(-c2ccc(-c3nc(-c4cc(-c5ccccc5)c(-n5c6ccc(-c7ccccc7)cc6c6cc(-c7ccccc7)ccc65)c(-c5ccccc5)c4)nc(-c4cccc5oc6ccccc6c45)n3)cc2)cc1 ; CC(C)(C)c1ccc2c(c1)c1cc(C(C)(C)C)ccc1n2-c1c(-c2ccccc2)cc(-c2nc(-c3ccccc3)nc(-c3cccc4oc5ccccc5c34)n2)cc1-c1ccccc1 ; CC(C)(C)c1ccc2c(c1)c1cc(C(C)(C)C)ccc1n2-c1c(-c2ccccc2)cc(-c2nc(-c3ccc(-c4ccccc4)cc3)nc(-c3cccc4oc5ccccc5c34)n2)cc1-c1ccccc1]

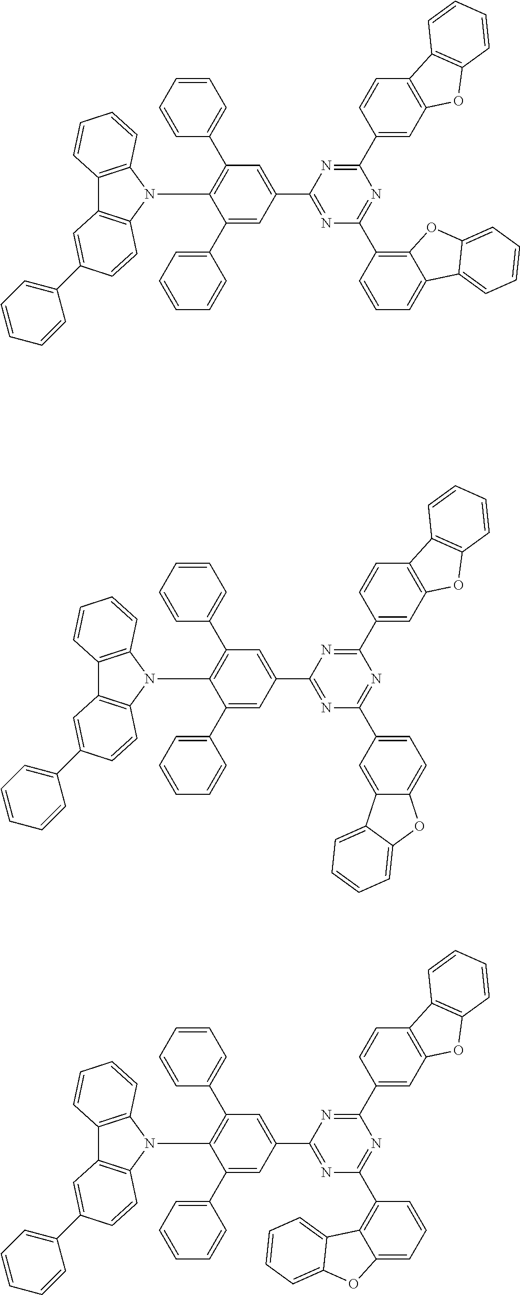 [SMILES: c1ccc(-c2ccc3c(c2)c2ccccc2n3-c2c(-c3ccccc3)cc(-c3nc(-c4ccc5c(c4)oc4ccccc45)nc(-c4cccc5c4oc4ccccc45)n3)cc2-c2ccccc2)cc1 ; c1ccc(-c2ccc3c(c2)c2ccccc2n3-c2c(-c3ccccc3)cc(-c3nc(-c4ccc5c(c4)oc4ccccc45)nc(-c4ccc5oc6ccccc6c5c4)n3)cc2-c2ccccc2)cc1 ; c1ccc(-c2ccc3c(c2)c2ccccc2n3-c2c(-c3ccccc3)cc(-c3nc(-c4ccc5c(c4)oc4ccccc45)nc(-c4cccc5oc6ccccc6c45)n3)cc2-c2ccccc2)cc1]

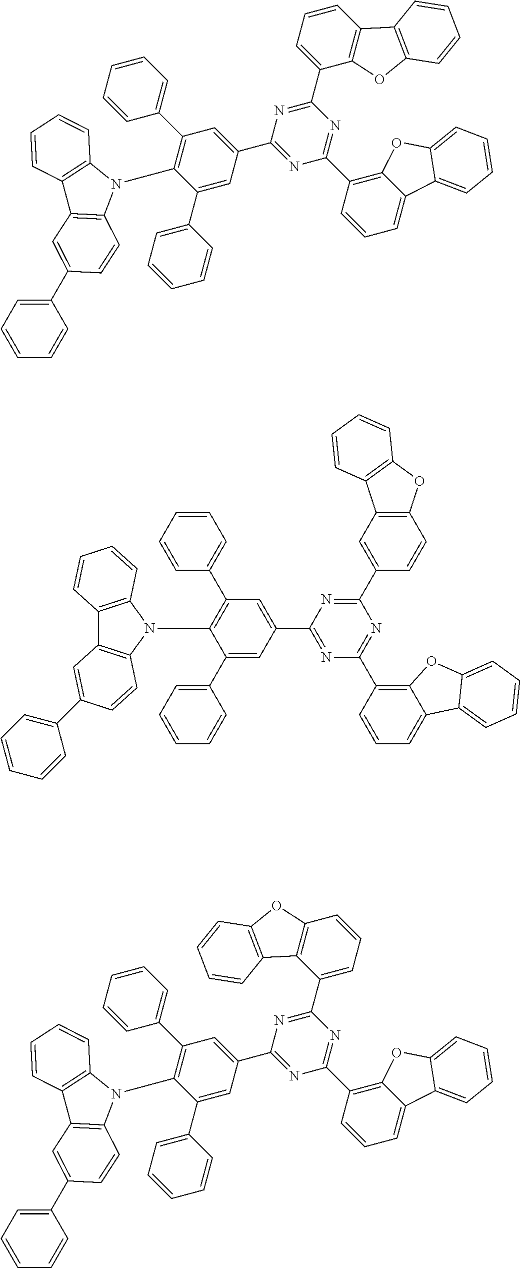 [SMILES: c1ccc(-c2ccc3c(c2)c2ccccc2n3-c2c(-c3ccccc3)cc(-c3nc(-c4cccc5c4oc4ccccc45)nc(-c4cccc5c4oc4ccccc45)n3)cc2-c2ccccc2)cc1 ; c1ccc(-c2ccc3c(c2)c2ccccc2n3-c2c(-c3ccccc3)cc(-c3nc(-c4ccc5oc6ccccc6c5c4)nc(-c4cccc5c4oc4ccccc45)n3)cc2-c2ccccc2)cc1 ; c1ccc(-c2ccc3c(c2)c2ccccc2n3-c2c(-c3ccccc3)cc(-c3nc(-c4cccc5c4oc4ccccc45)nc(-c4cccc5oc6ccccc6c45)n3)cc2-c2ccccc2)cc1]

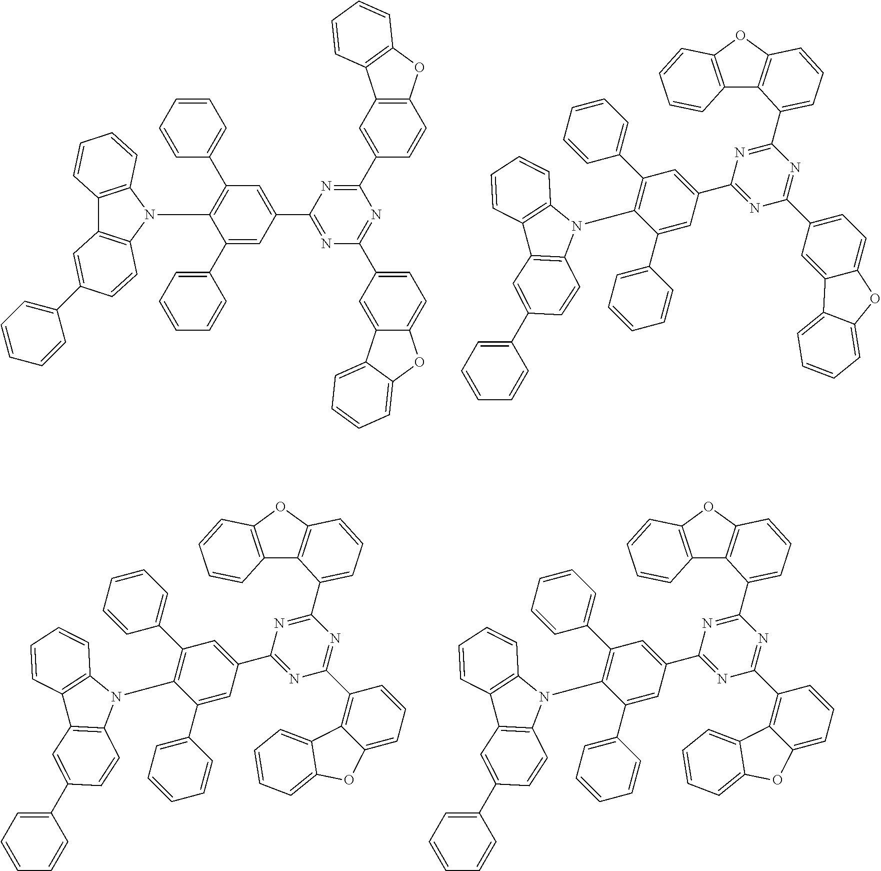

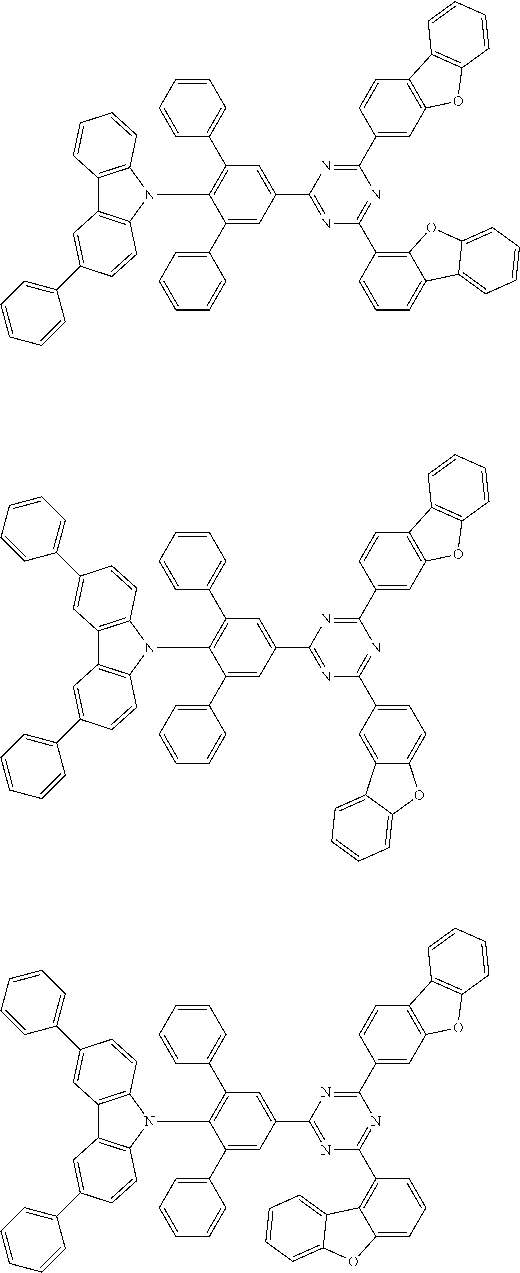 [SMILES: c1ccc(-c2ccc3c(c2)c2ccccc2n3-c2c(-c3ccccc3)cc(-c3nc(-c4ccc5c(c4)oc4ccccc45)nc(-c4cccc5c4oc4ccccc45)n3)cc2-c2ccccc2)cc1 ; c1ccc(-c2ccc3c(c2)c2cc(-c4ccccc4)ccc2n3-c2c(-c3ccccc3)cc(-c3nc(-c4ccc5c(c4)oc4ccccc45)nc(-c4ccc5oc6ccccc6c5c4)n3)cc2-c2ccccc2)cc1 ; c1ccc(-c2ccc3c(c2)c2cc(-c4ccccc4)ccc2n3-c2c(-c3ccccc3)cc(-c3nc(-c4ccc5c(c4)oc4ccccc45)nc(-c4cccc5oc6ccccc6c45)n3)cc2-c2ccccc2)cc1]

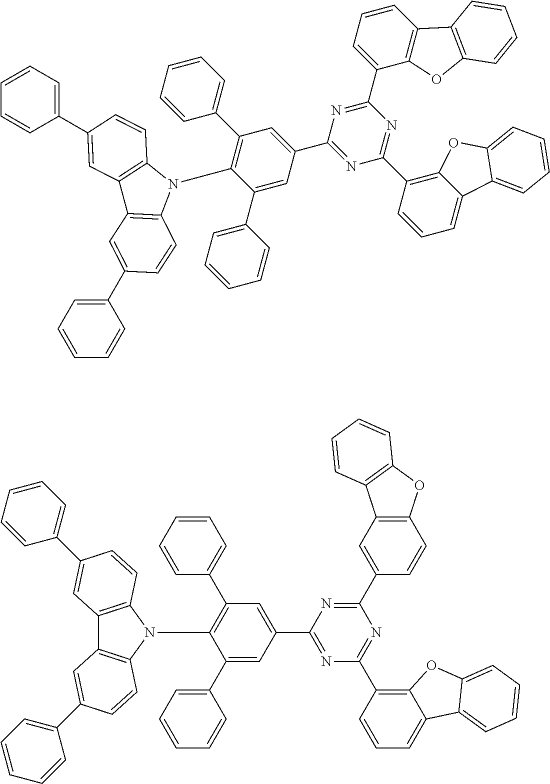 [SMILES: c1ccc(-c2ccc3c(c2)c2cc(-c4ccccc4)ccc2n3-c2c(-c3ccccc3)cc(-c3nc(-c4cccc5c4oc4ccccc45)nc(-c4cccc5c4oc4ccccc45)n3)cc2-c2ccccc2)cc1 ; c1ccc(-c2ccc3c(c2)c2cc(-c4ccccc4)ccc2n3-c2c(-c3ccccc3)cc(-c3nc(-c4ccc5oc6ccccc6c5c4)nc(-c4cccc5c4oc4ccccc45)n3)cc2-c2ccccc2)cc1]

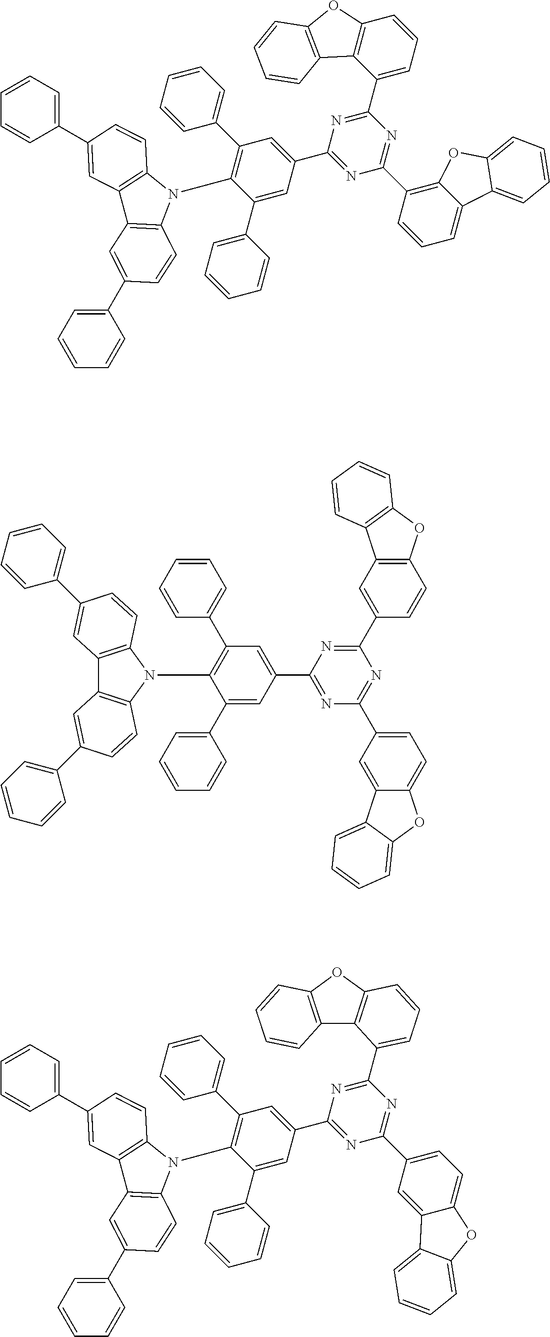 [SMILES: c1ccc(-c2ccc3c(c2)c2cc(-c4ccccc4)ccc2n3-c2c(-c3ccccc3)cc(-c3nc(-c4cccc5c4oc4ccccc45)nc(-c4cccc5oc6ccccc6c45)n3)cc2-c2ccccc2)cc1 ; c1ccc(-c2ccc3c(c2)c2cc(-c4ccccc4)ccc2n3-c2c(-c3ccccc3)cc(-c3nc(-c4ccc5oc6ccccc6c5c4)nc(-c4ccc5oc6ccccc6c5c4)n3)cc2-c2ccccc2)cc1 ; c1ccc(-c2ccc3c(c2)c2cc(-c4ccccc4)ccc2n3-c2c(-c3ccccc3)cc(-c3nc(-c4ccc5oc6ccccc6c5c4)nc(-c4cccc5oc6ccccc6c45)n3)cc2-c2ccccc2)cc1]

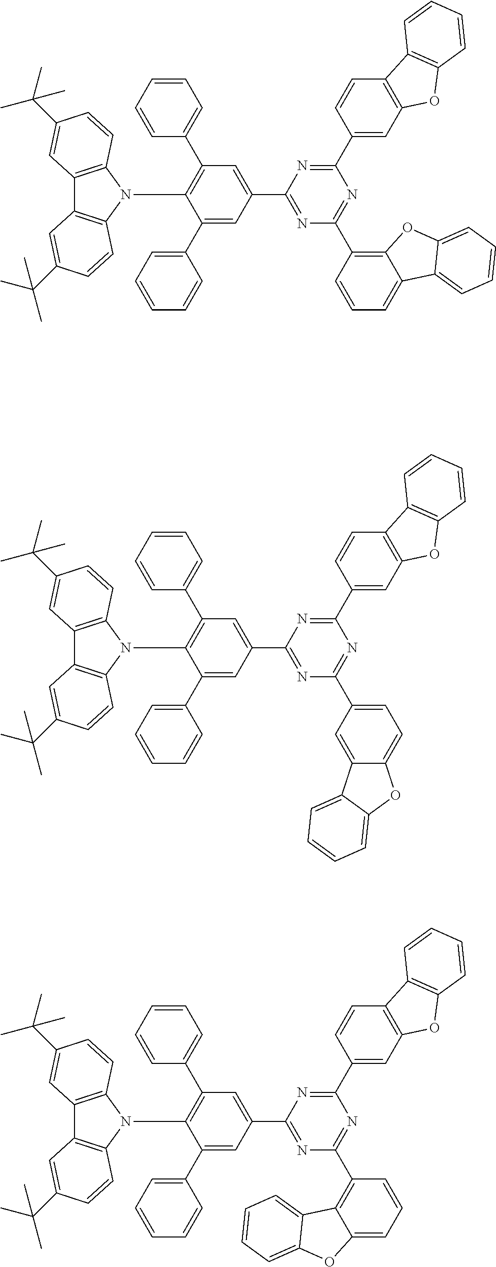 [SMILES: CC(C)(C)c1ccc2c(c1)c1cc(C(C)(C)C)ccc1n2-c1c(-c2ccccc2)cc(-c2nc(-c3ccc4c(c3)oc3ccccc34)nc(-c3cccc4c3oc3ccccc34)n2)cc1-c1ccccc1 ; CC(C)(C)c1ccc2c(c1)c1cc(C(C)(C)C)ccc1n2-c1c(-c2ccccc2)cc(-c2nc(-c3ccc4c(c3)oc3ccccc34)nc(-c3ccc4oc5ccccc5c4c3)n2)cc1-c1ccccc1 ; CC(C)(C)c1ccc2c(c1)c1cc(C(C)(C)C)ccc1n2-c1c(-c2ccccc2)cc(-c2nc(-c3ccc4c(c3)oc3ccccc34)nc(-c3cccc4oc5ccccc5c34)n2)cc1-c1ccccc1]

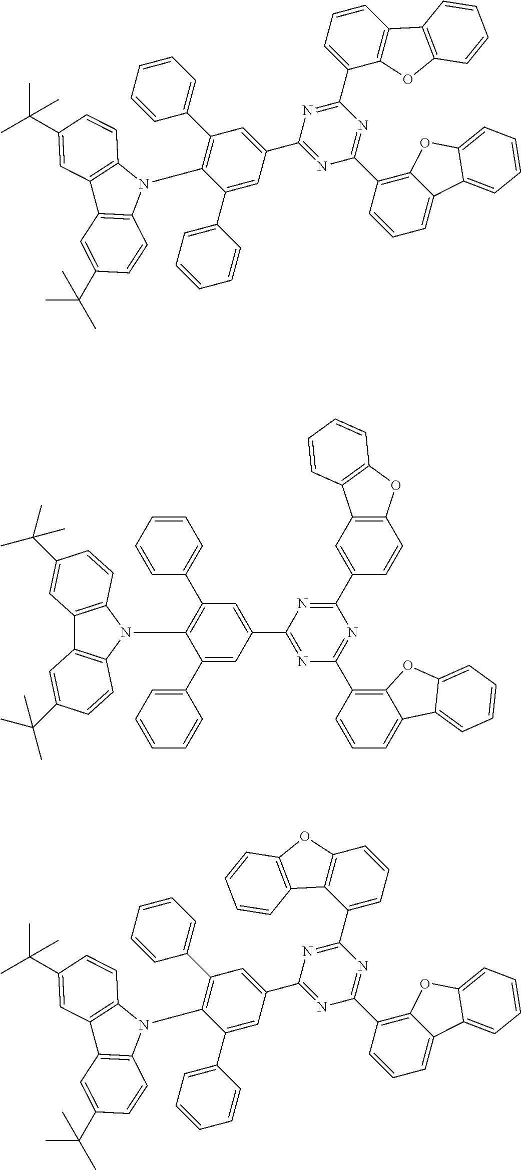 [SMILES: CC(C)(C)c1ccc2c(c1)c1cc(C(C)(C)C)ccc1n2-c1c(-c2ccccc2)cc(-c2nc(-c3cccc4c3oc3ccccc34)nc(-c3cccc4c3oc3ccccc34)n2)cc1-c1ccccc1 ; CC(C)(C)c1ccc2c(c1)c1cc(C(C)(C)C)ccc1n2-c1c(-c2ccccc2)cc(-c2nc(-c3ccc4oc5ccccc5c4c3)nc(-c3cccc4c3oc3ccccc34)n2)cc1-c1ccccc1 ; CC(C)(C)c1ccc2c(c1)c1cc(C(C)(C)C)ccc1n2-c1c(-c2ccccc2)cc(-c2nc(-c3cccc4c3oc3ccccc34)nc(-c3cccc4oc5ccccc5c34)n2)cc1-c1ccccc1]

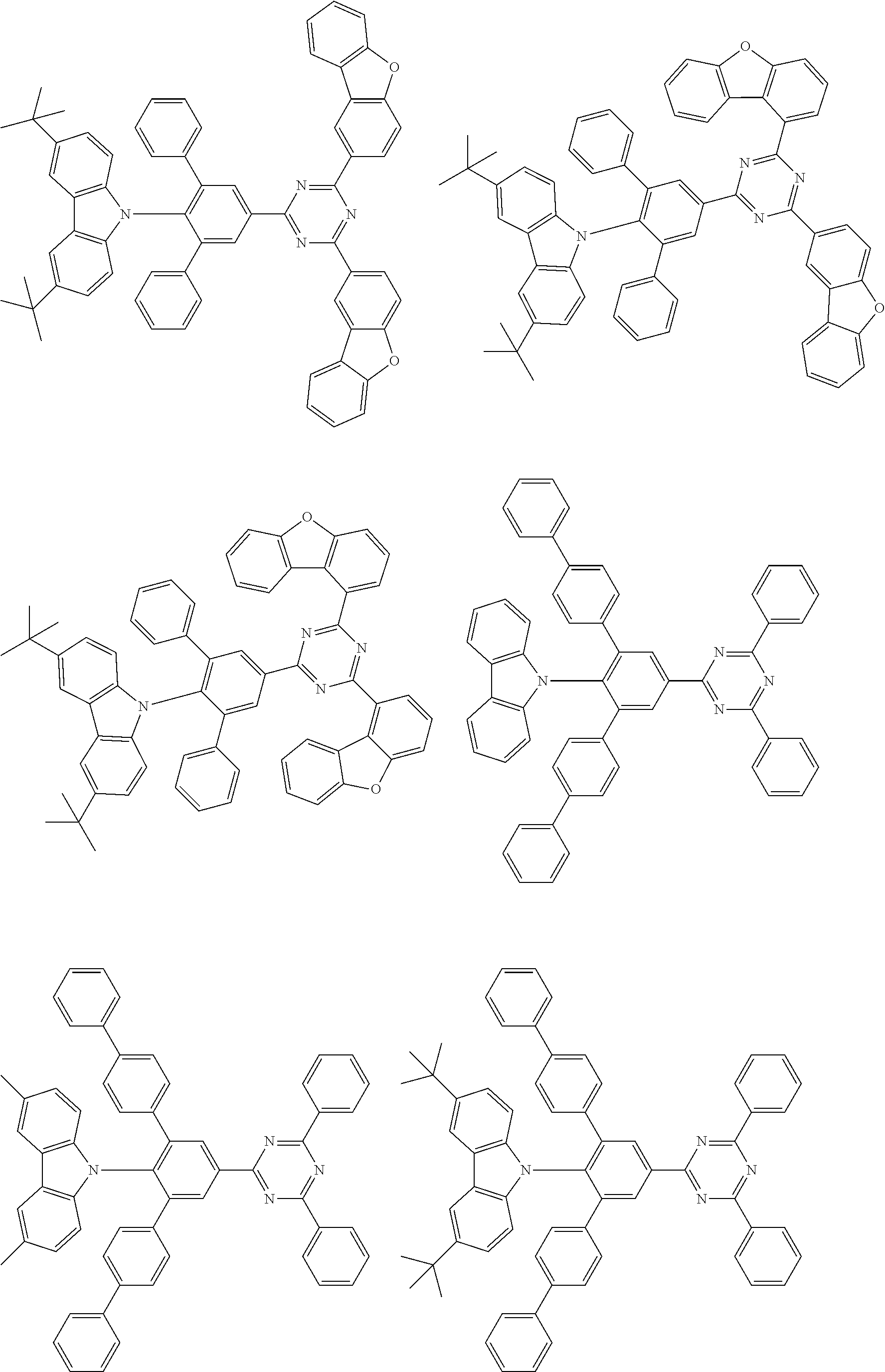

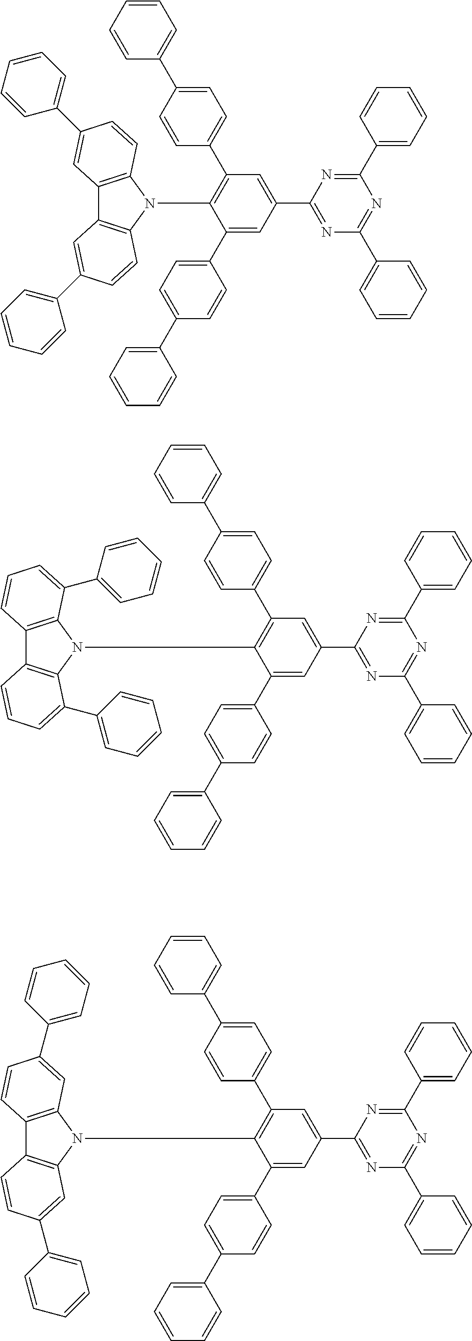

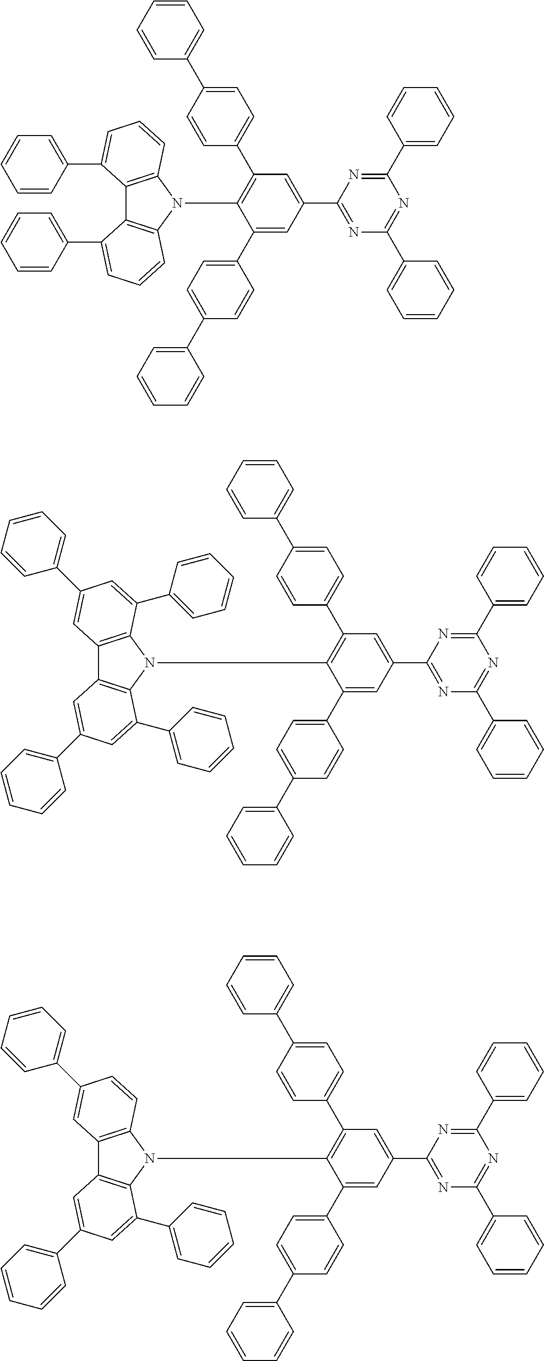 [SMILES: c1ccc(-c2ccc(-c3cc(-c4nc(-c5ccccc5)nc(-c5ccccc5)n4)cc(-c4ccc(-c5ccccc5)cc4)c3-n3c4cccc(-c5ccccc5)c4c4c(-c5ccccc5)cccc43)cc2)cc1 ; c1ccc(-c2ccc(-c3cc(-c4nc(-c5ccccc5)nc(-c5ccccc5)n4)cc(-c4ccc(-c5ccccc5)cc4)c3-n3c4c(-c5ccccc5)cc(-c5ccccc5)cc4c4cc(-c5ccccc5)cc(-c5ccccc5)c43)cc2)cc1 ; c1ccc(-c2ccc(-c3cc(-c4nc(-c5ccccc5)nc(-c5ccccc5)n4)cc(-c4ccc(-c5ccccc5)cc4)c3-n3c4ccc(-c5ccccc5)cc4c4cc(-c5ccccc5)cc(-c5ccccc5)c43)cc2)cc1]

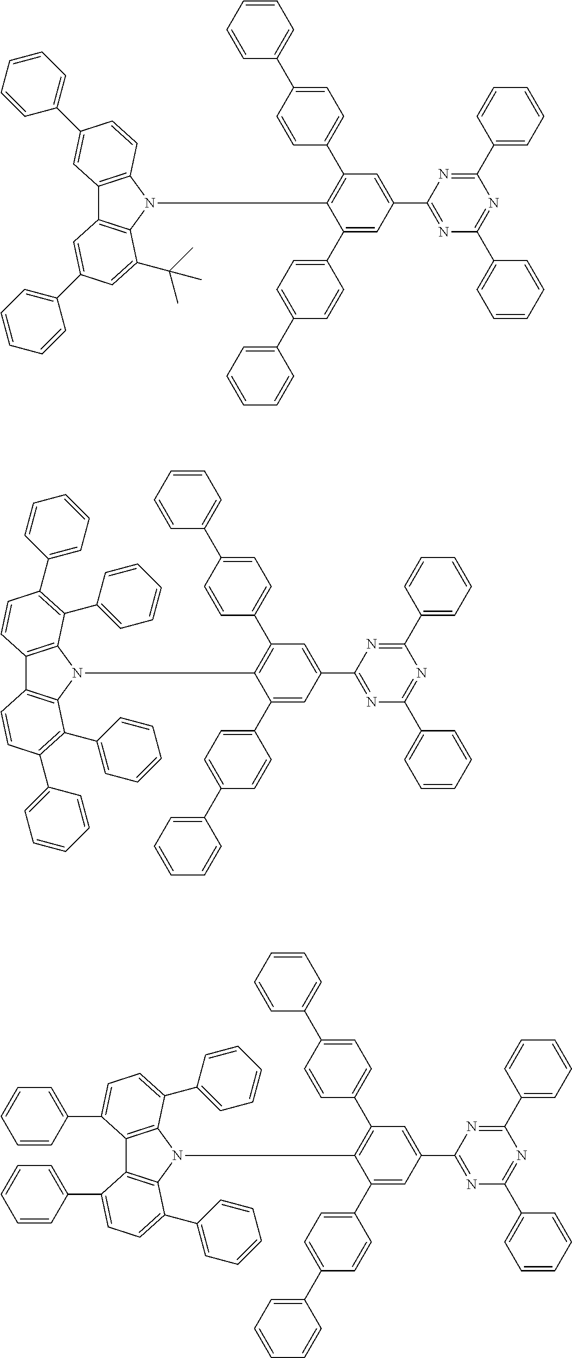 [SMILES: CC(C)(C)c1cc(-c2ccccc2)cc2c3cc(-c4ccccc4)ccc3n(-c3c(-c4ccc(-c5ccccc5)cc4)cc(-c4nc(-c5ccccc5)nc(-c5ccccc5)n4)cc3-c3ccc(-c4ccccc4)cc3)c12 ; c1ccc(-c2ccc(-c3cc(-c4nc(-c5ccccc5)nc(-c5ccccc5)n4)cc(-c4ccc(-c5ccccc5)cc4)c3-n3c4c(-c5ccccc5)c(-c5ccccc5)ccc4c4ccc(-c5ccccc5)c(-c5ccccc5)c43)cc2)cc1 ; c1ccc(-c2ccc(-c3cc(-c4nc(-c5ccccc5)nc(-c5ccccc5)n4)cc(-c4ccc(-c5ccccc5)cc4)c3-n3c4c(-c5ccccc5)ccc(-c5ccccc5)c4c4c(-c5ccccc5)ccc(-c5ccccc5)c43)cc2)cc1]

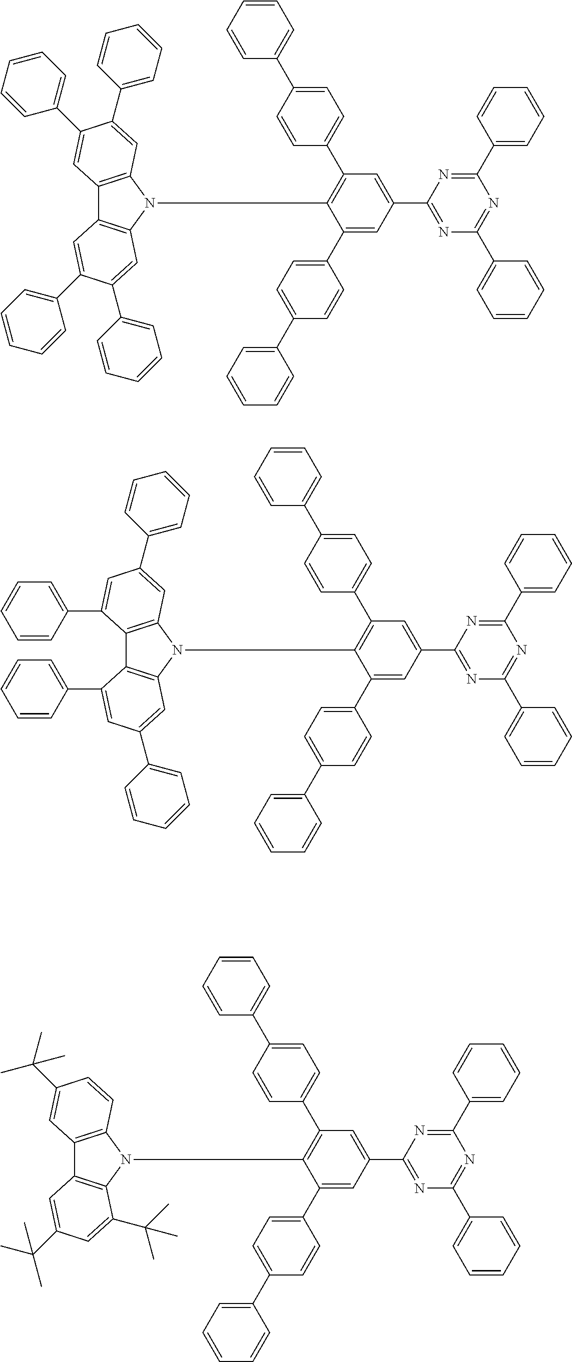

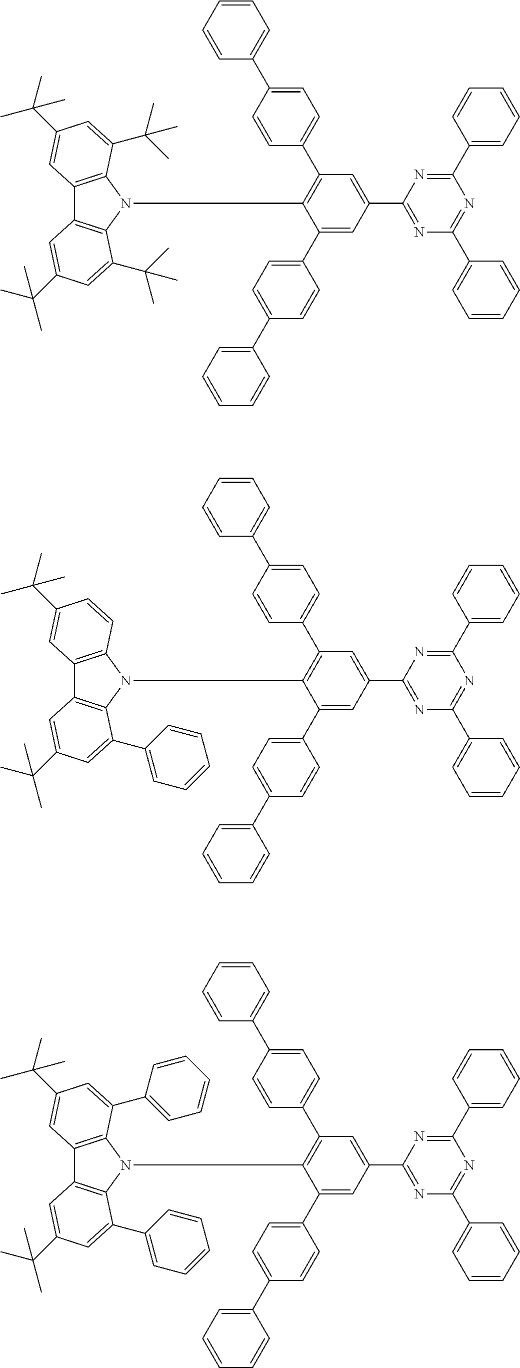 [SMILES: CC(C)(C)c1cc(C(C)(C)C)c2c(c1)c1cc(C(C)(C)C)cc(C(C)(C)C)c1n2-c1c(-c2ccc(-c3ccccc3)cc2)cc(-c2nc(-c3ccccc3)nc(-c3ccccc3)n2)cc1-c1ccc(-c2ccccc2)cc1 ; CC(C)(C)c1ccc2c(c1)c1cc(C(C)(C)C)cc(-c3ccccc3)c1n2-c1c(-c2ccc(-c3ccccc3)cc2)cc(-c2nc(-c3ccccc3)nc(-c3ccccc3)n2)cc1-c1ccc(-c2ccccc2)cc1 ; CC(C)(C)c1cc(-c2ccccc2)c2c(c1)c1cc(C(C)(C)C)cc(-c3ccccc3)c1n2-c1c(-c2ccc(-c3ccccc3)cc2)cc(-c2nc(-c3ccccc3)nc(-c3ccccc3)n2)cc1-c1ccc(-c2ccccc2)cc1]

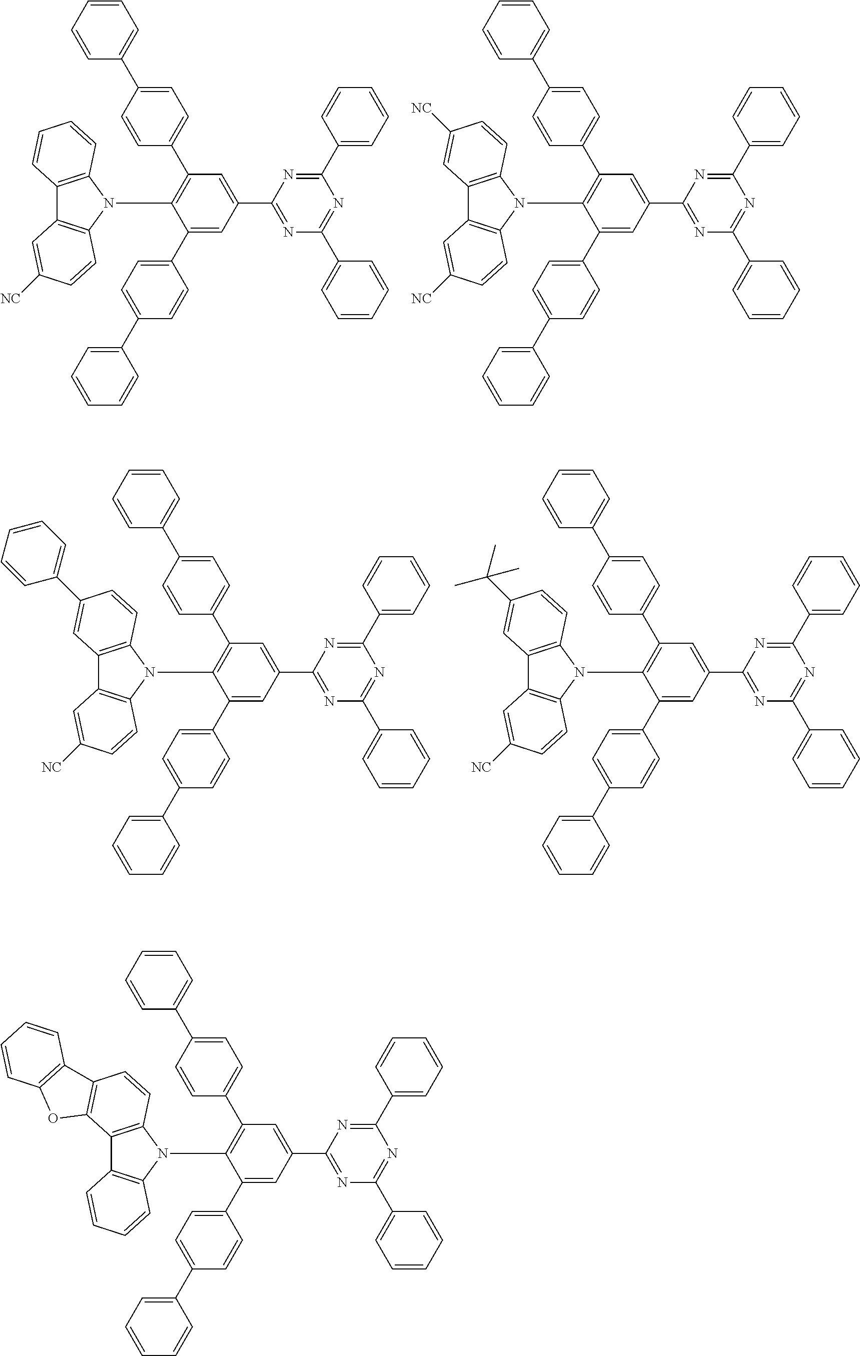

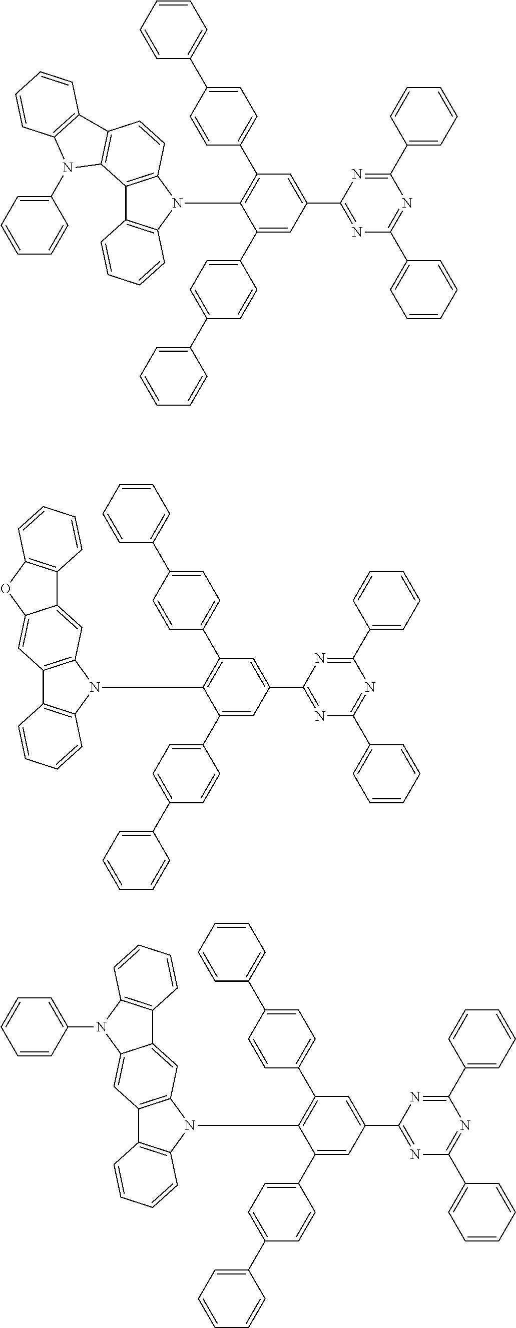 [SMILES: c1ccc(-c2ccc(-c3cc(-c4nc(-c5ccccc5)nc(-c5ccccc5)n4)cc(-c4ccc(-c5ccccc5)cc4)c3-n3c4ccccc4c4c3ccc3c5ccccc5n(-c5ccccc5)c34)cc2)cc1 ; c1ccc(-c2ccc(-c3cc(-c4nc(-c5ccccc5)nc(-c5ccccc5)n4)cc(-c4ccc(-c5ccccc5)cc4)c3-n3c4ccccc4c4cc5oc6ccccc6c5cc43)cc2)cc1 ; c1ccc(-c2ccc(-c3cc(-c4nc(-c5ccccc5)nc(-c5ccccc5)n4)cc(-c4ccc(-c5ccccc5)cc4)c3-n3c4ccccc4c4cc5c(cc43)c3ccccc3n5-c3ccccc3)cc2)cc1]

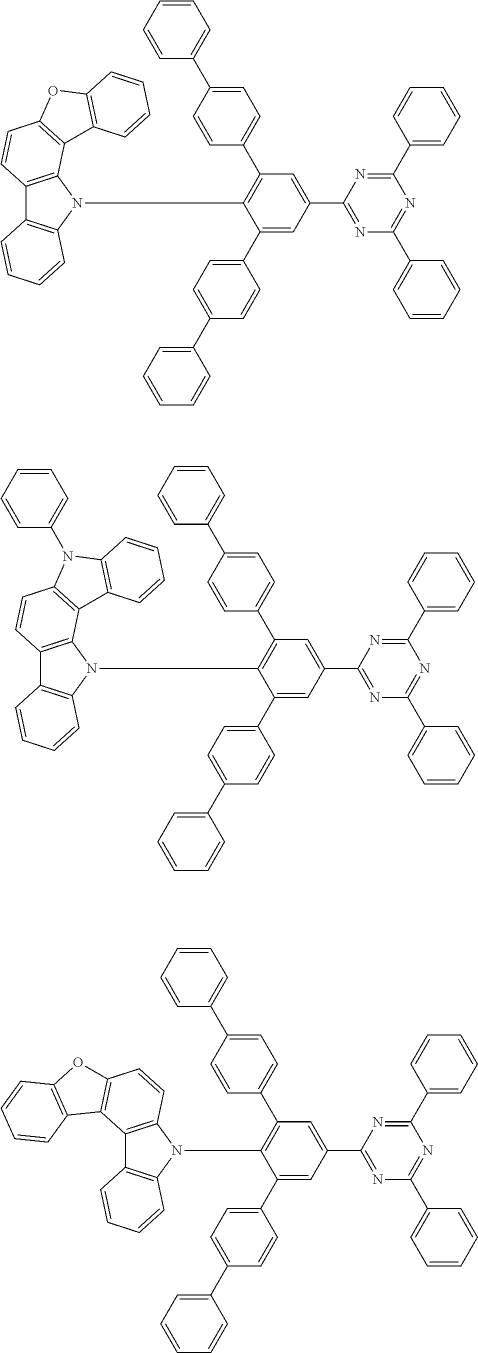 [SMILES: c1ccc(-c2ccc(-c3cc(-c4nc(-c5ccccc5)nc(-c5ccccc5)n4)cc(-c4ccc(-c5ccccc5)cc4)c3-n3c4ccccc4c4ccc5oc6ccccc6c5c43)cc2)cc1 ; c1ccc(-c2ccc(-c3cc(-c4nc(-c5ccccc5)nc(-c5ccccc5)n4)cc(-c4ccc(-c5ccccc5)cc4)c3-n3c4ccccc4c4ccc5c(c6ccccc6n5-c5ccccc5)c43)cc2)cc1 ; c1ccc(-c2ccc(-c3cc(-c4nc(-c5ccccc5)nc(-c5ccccc5)n4)cc(-c4ccc(-c5ccccc5)cc4)c3-n3c4ccccc4c4c5c(ccc43)oc3ccccc35)cc2)cc1]

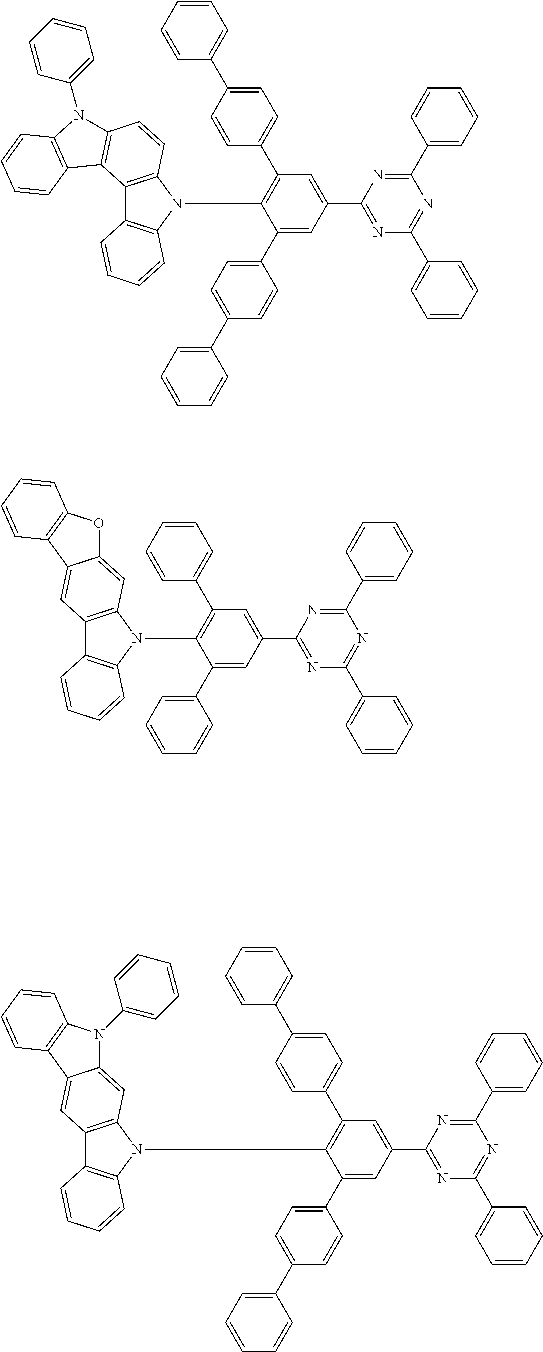 [SMILES: c1ccc(-c2ccc(-c3cc(-c4nc(-c5ccccc5)nc(-c5ccccc5)n4)cc(-c4ccc(-c5ccccc5)cc4)c3-n3c4ccccc4c4c5c6ccccc6n(-c6ccccc6)c5ccc43)cc2)cc1 ; c1ccc(-c2nc(-c3ccccc3)nc(-c3cc(-c4ccccc4)c(-n4c5ccccc5c5cc6c(cc54)oc4ccccc46)c(-c4ccccc4)c3)n2)cc1 ; c1ccc(-c2ccc(-c3cc(-c4nc(-c5ccccc5)nc(-c5ccccc5)n4)cc(-c4ccc(-c5ccccc5)cc4)c3-n3c4ccccc4c4cc5c6ccccc6n(-c6ccccc6)c5cc43)cc2)cc1]

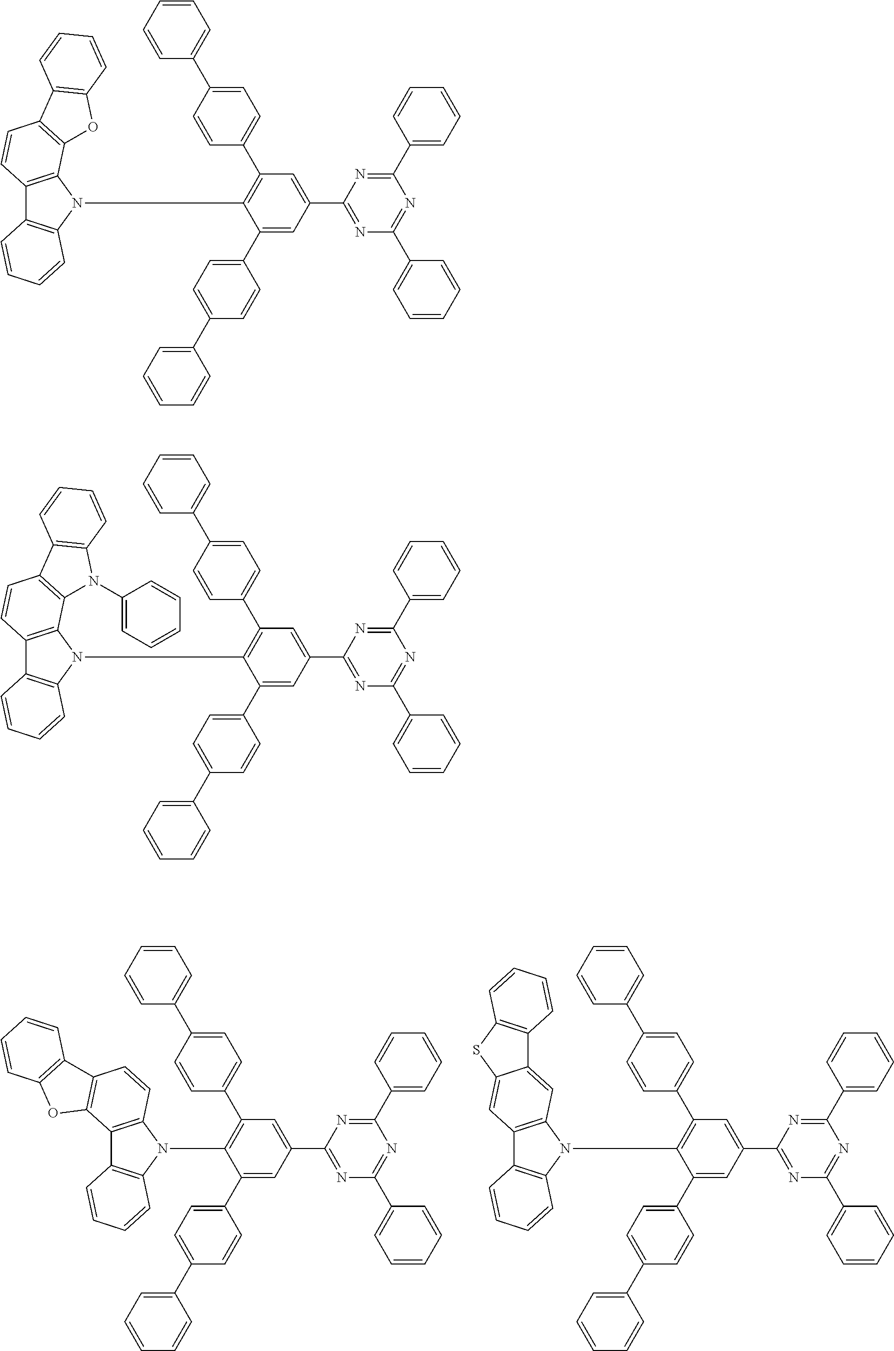

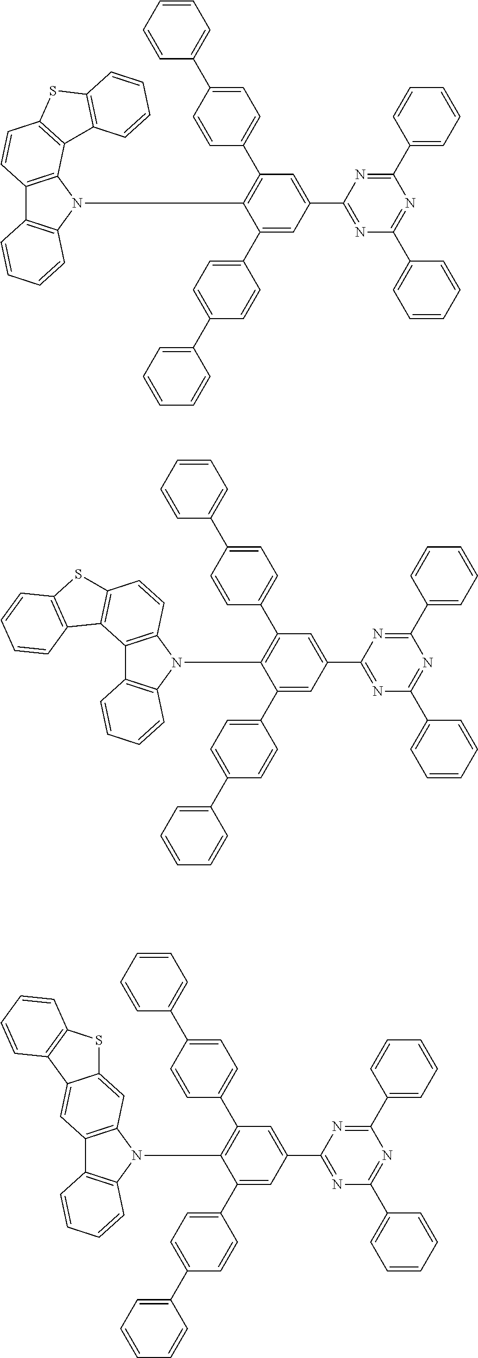 [SMILES: c1ccc(-c2ccc(-c3cc(-c4nc(-c5ccccc5)nc(-c5ccccc5)n4)cc(-c4ccc(-c5ccccc5)cc4)c3-n3c4ccccc4c4ccc5sc6ccccc6c5c43)cc2)cc1 ; c1ccc(-c2ccc(-c3cc(-c4nc(-c5ccccc5)nc(-c5ccccc5)n4)cc(-c4ccc(-c5ccccc5)cc4)c3-n3c4ccccc4c4c5c(ccc43)sc3ccccc35)cc2)cc1 ; c1ccc(-c2ccc(-c3cc(-c4nc(-c5ccccc5)nc(-c5ccccc5)n4)cc(-c4ccc(-c5ccccc5)cc4)c3-n3c4ccccc4c4cc5c(cc43)sc3ccccc35)cc2)cc1]

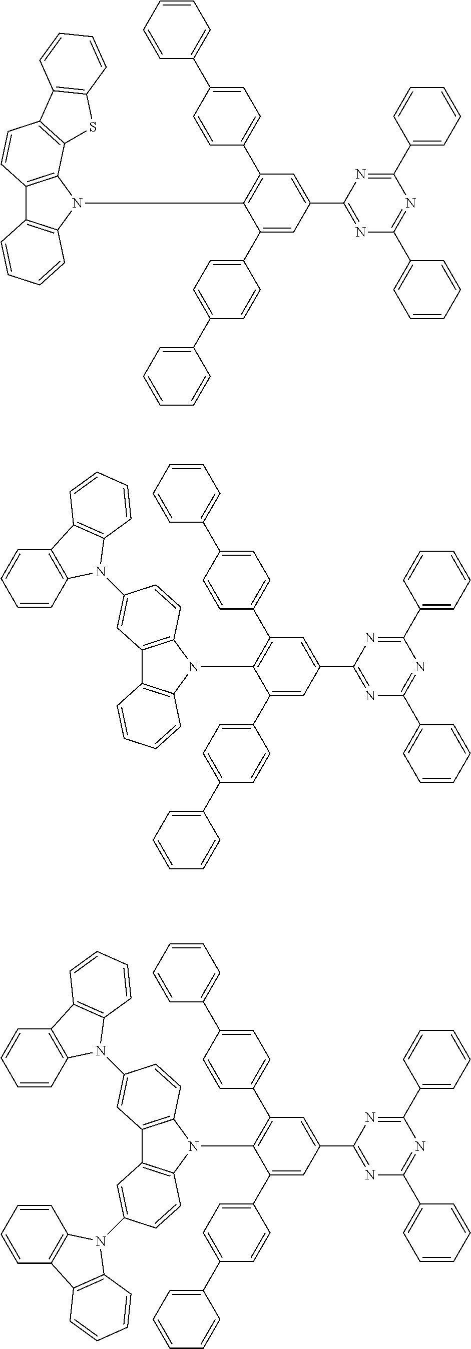 [SMILES: c1ccc(-c2ccc(-c3cc(-c4nc(-c5ccccc5)nc(-c5ccccc5)n4)cc(-c4ccc(-c5ccccc5)cc4)c3-n3c4ccccc4c4ccc5c6ccccc6sc5c43)cc2)cc1 ; c1ccc(-c2ccc(-c3cc(-c4nc(-c5ccccc5)nc(-c5ccccc5)n4)cc(-c4ccc(-c5ccccc5)cc4)c3-n3c4ccccc4c4cc(-n5c6ccccc6c6ccccc65)ccc43)cc2)cc1 ; c1ccc(-c2ccc(-c3cc(-c4nc(-c5ccccc5)nc(-c5ccccc5)n4)cc(-c4ccc(-c5ccccc5)cc4)c3-n3c4ccc(-n5c6ccccc6c6ccccc65)cc4c4cc(-n5c6ccccc6c6ccccc65)ccc43)cc2)cc1]

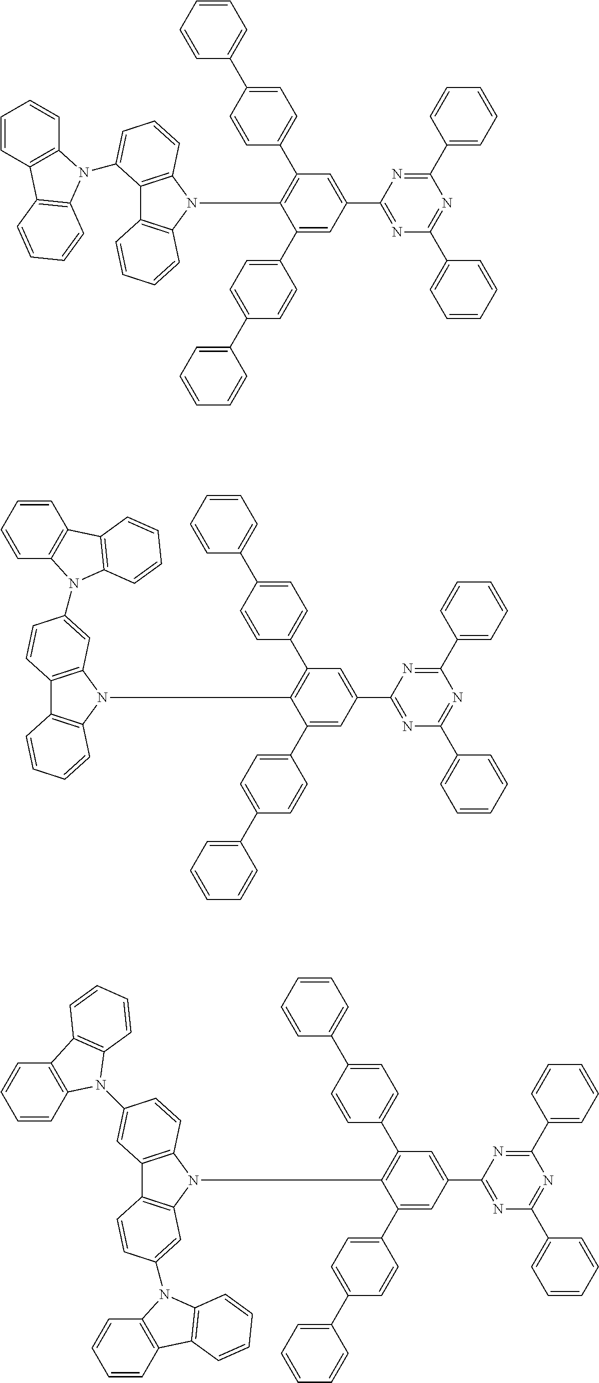 [SMILES: c1ccc(-c2ccc(-c3cc(-c4nc(-c5ccccc5)nc(-c5ccccc5)n4)cc(-c4ccc(-c5ccccc5)cc4)c3-n3c4ccccc4c4c(-n5c6ccccc6c6ccccc65)cccc43)cc2)cc1 ; c1ccc(-c2ccc(-c3cc(-c4nc(-c5ccccc5)nc(-c5ccccc5)n4)cc(-c4ccc(-c5ccccc5)cc4)c3-n3c4ccccc4c4ccc(-n5c6ccccc6c6ccccc65)cc43)cc2)cc1 ; c1ccc(-c2ccc(-c3cc(-c4nc(-c5ccccc5)nc(-c5ccccc5)n4)cc(-c4ccc(-c5ccccc5)cc4)c3-n3c4ccc(-n5c6ccccc6c6ccccc65)cc4c4ccc(-n5c6ccccc6c6ccccc65)cc43)cc2)cc1]

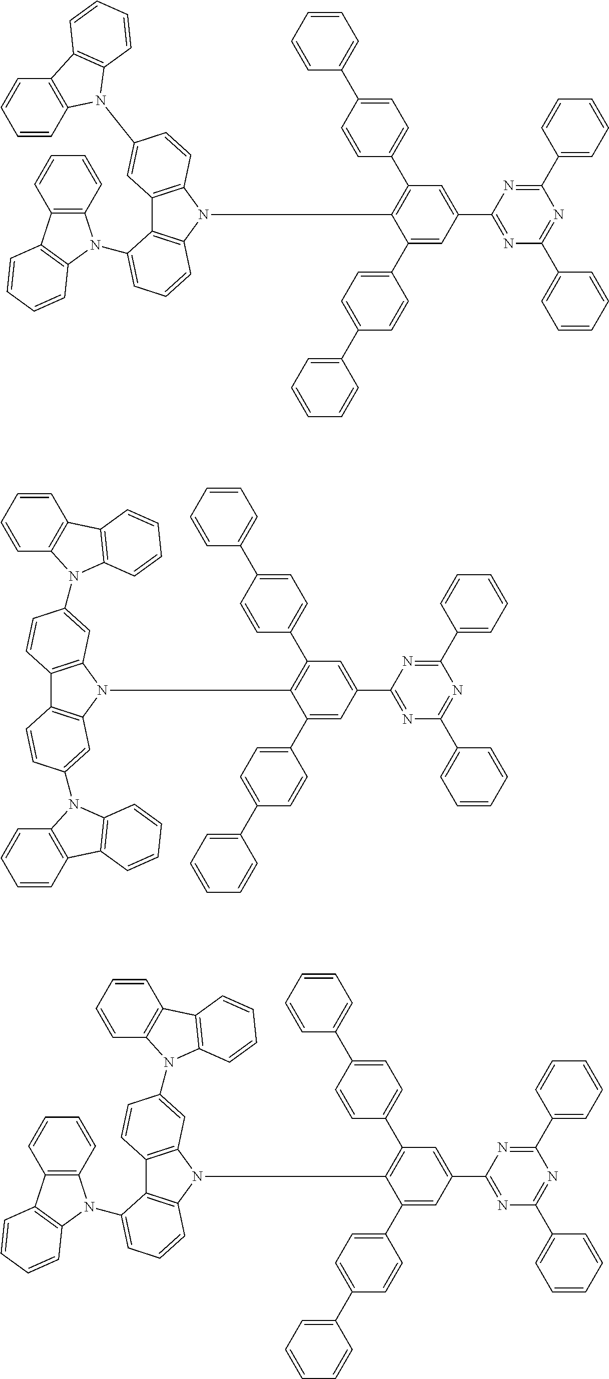 [SMILES: c1ccc(-c2ccc(-c3cc(-c4nc(-c5ccccc5)nc(-c5ccccc5)n4)cc(-c4ccc(-c5ccccc5)cc4)c3-n3c4ccc(-n5c6ccccc6c6ccccc65)cc4c4c(-n5c6ccccc6c6ccccc65)cccc43)cc2)cc1 ; c1ccc(-c2ccc(-c3cc(-c4nc(-c5ccccc5)nc(-c5ccccc5)n4)cc(-c4ccc(-c5ccccc5)cc4)c3-n3c4cc(-n5c6ccccc6c6ccccc65)ccc4c4ccc(-n5c6ccccc6c6ccccc65)cc43)cc2)cc1 ; c1ccc(-c2ccc(-c3cc(-c4nc(-c5ccccc5)nc(-c5ccccc5)n4)cc(-c4ccc(-c5ccccc5)cc4)c3-n3c4cc(-n5c6ccccc6c6ccccc65)ccc4c4c(-n5c6ccccc6c6ccccc65)cccc43)cc2)cc1]

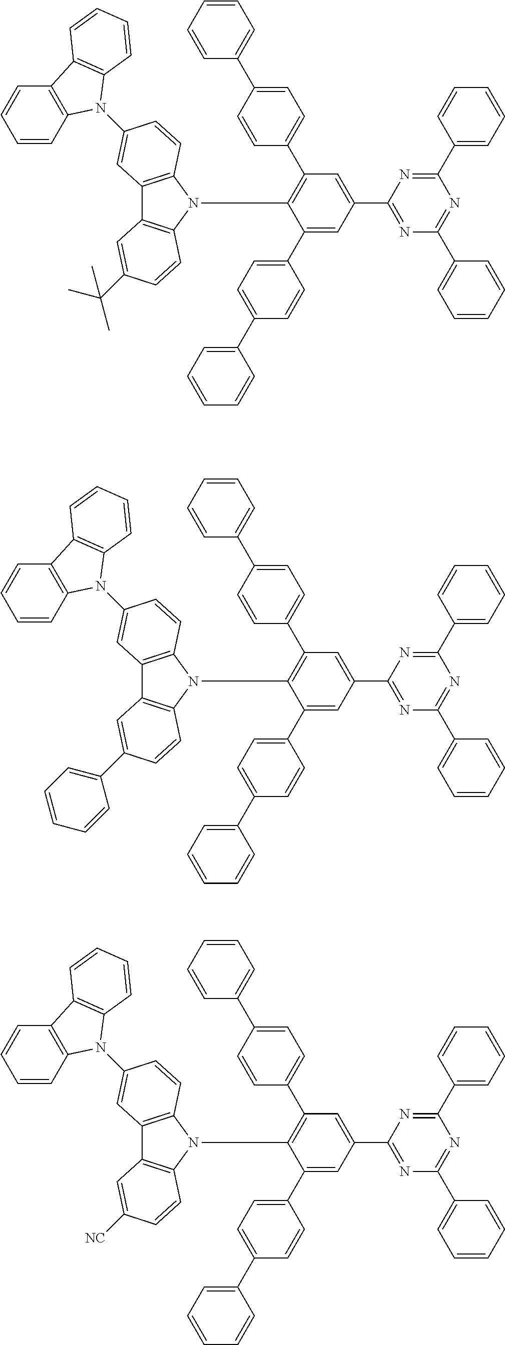 [SMILES: CC(C)(C)c1ccc2c(c1)c1cc(-n3c4ccccc4c4ccccc43)ccc1n2-c1c(-c2ccc(-c3ccccc3)cc2)cc(-c2nc(-c3ccccc3)nc(-c3ccccc3)n2)cc1-c1ccc(-c2ccccc2)cc1 ; c1ccc(-c2ccc(-c3cc(-c4nc(-c5ccccc5)nc(-c5ccccc5)n4)cc(-c4ccc(-c5ccccc5)cc4)c3-n3c4ccc(-c5ccccc5)cc4c4cc(-n5c6ccccc6c6ccccc65)ccc43)cc2)cc1 ; N#Cc1ccc2c(c1)c1cc(-n3c4ccccc4c4ccccc43)ccc1n2-c1c(-c2ccc(-c3ccccc3)cc2)cc(-c2nc(-c3ccccc3)nc(-c3ccccc3)n2)cc1-c1ccc(-c2ccccc2)cc1]

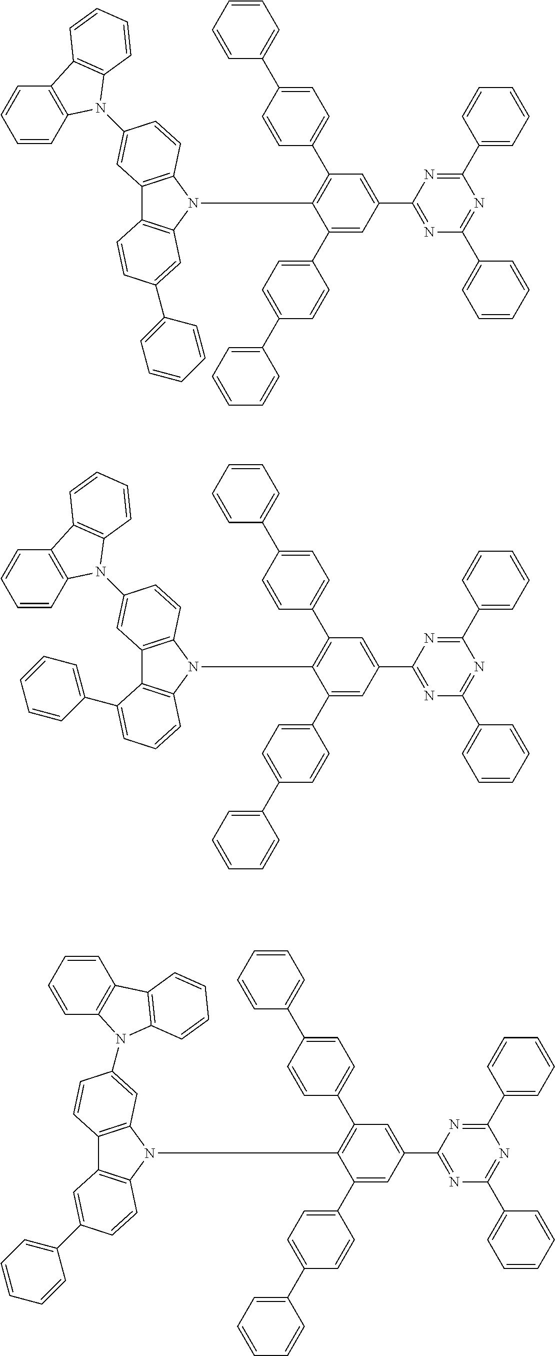 [SMILES: c1ccc(-c2ccc(-c3cc(-c4nc(-c5ccccc5)nc(-c5ccccc5)n4)cc(-c4ccc(-c5ccccc5)cc4)c3-n3c4ccc(-n5c6ccccc6c6ccccc65)cc4c4ccc(-c5ccccc5)cc43)cc2)cc1 ; c1ccc(-c2ccc(-c3cc(-c4nc(-c5ccccc5)nc(-c5ccccc5)n4)cc(-c4ccc(-c5ccccc5)cc4)c3-n3c4ccc(-n5c6ccccc6c6ccccc65)cc4c4c(-c5ccccc5)cccc43)cc2)cc1 ; c1ccc(-c2ccc(-c3cc(-c4nc(-c5ccccc5)nc(-c5ccccc5)n4)cc(-c4ccc(-c5ccccc5)cc4)c3-n3c4ccc(-c5ccccc5)cc4c4ccc(-n5c6ccccc6c6ccccc65)cc43)cc2)cc1]

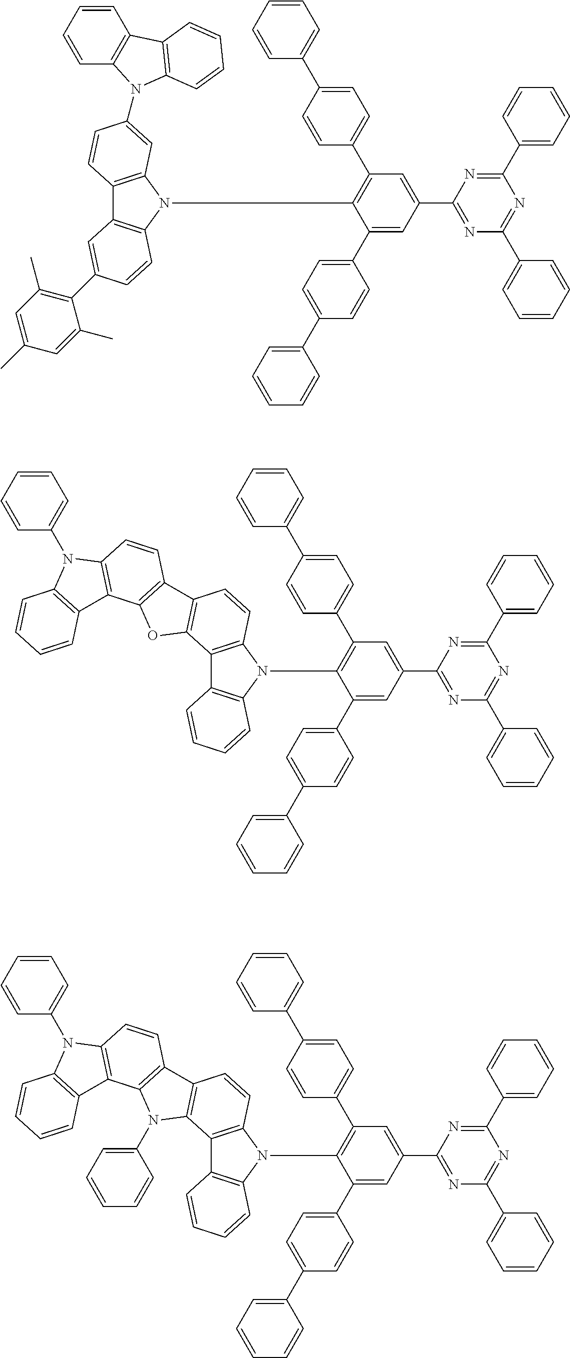 [SMILES: Cc1cc(C)c(-c2ccc3c(c2)c2ccc(-n4c5ccccc5c5ccccc54)cc2n3-c2c(-c3ccc(-c4ccccc4)cc3)cc(-c3nc(-c4ccccc4)nc(-c4ccccc4)n3)cc2-c2ccc(-c3ccccc3)cc2)c(C)c1 ; c1ccc(-c2ccc(-c3cc(-c4nc(-c5ccccc5)nc(-c5ccccc5)n4)cc(-c4ccc(-c5ccccc5)cc4)c3-n3c4ccccc4c4c5oc6c(ccc7c6c6ccccc6n7-c6ccccc6)c5ccc43)cc2)cc1 ; c1ccc(-c2ccc(-c3cc(-c4nc(-c5ccccc5)nc(-c5ccccc5)n4)cc(-c4ccc(-c5ccccc5)cc4)c3-n3c4ccccc4c4c3ccc3c5ccc6c(c7ccccc7n6-c6ccccc6)c5n(-c5ccccc5)c34)cc2)cc1]

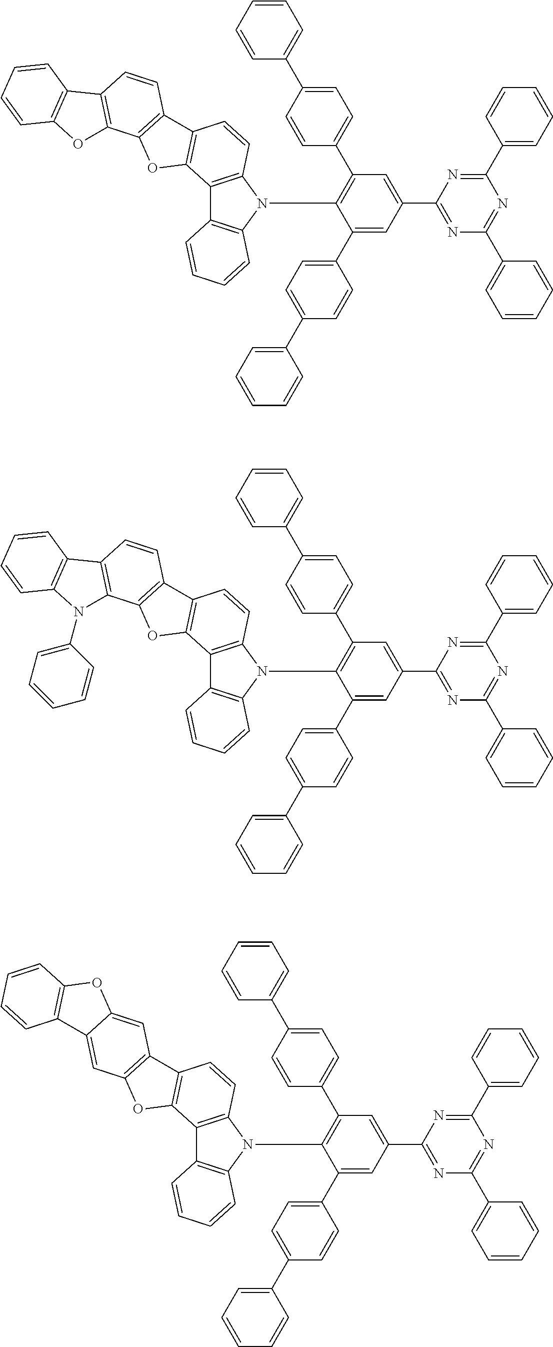 [SMILES: c1ccc(-c2ccc(-c3cc(-c4nc(-c5ccccc5)nc(-c5ccccc5)n4)cc(-c4ccc(-c5ccccc5)cc4)c3-n3c4ccccc4c4c5oc6c(ccc7c8ccccc8oc76)c5ccc43)cc2)cc1 ; c1ccc(-c2ccc(-c3cc(-c4nc(-c5ccccc5)nc(-c5ccccc5)n4)cc(-c4ccc(-c5ccccc5)cc4)c3-n3c4ccccc4c4c5oc6c(ccc7c8ccccc8n(-c8ccccc8)c76)c5ccc43)cc2)cc1 ; c1ccc(-c2ccc(-c3cc(-c4nc(-c5ccccc5)nc(-c5ccccc5)n4)cc(-c4ccc(-c5ccccc5)cc4)c3-n3c4ccccc4c4c5oc6cc7c(cc6c5ccc43)oc3ccccc37)cc2)cc1]

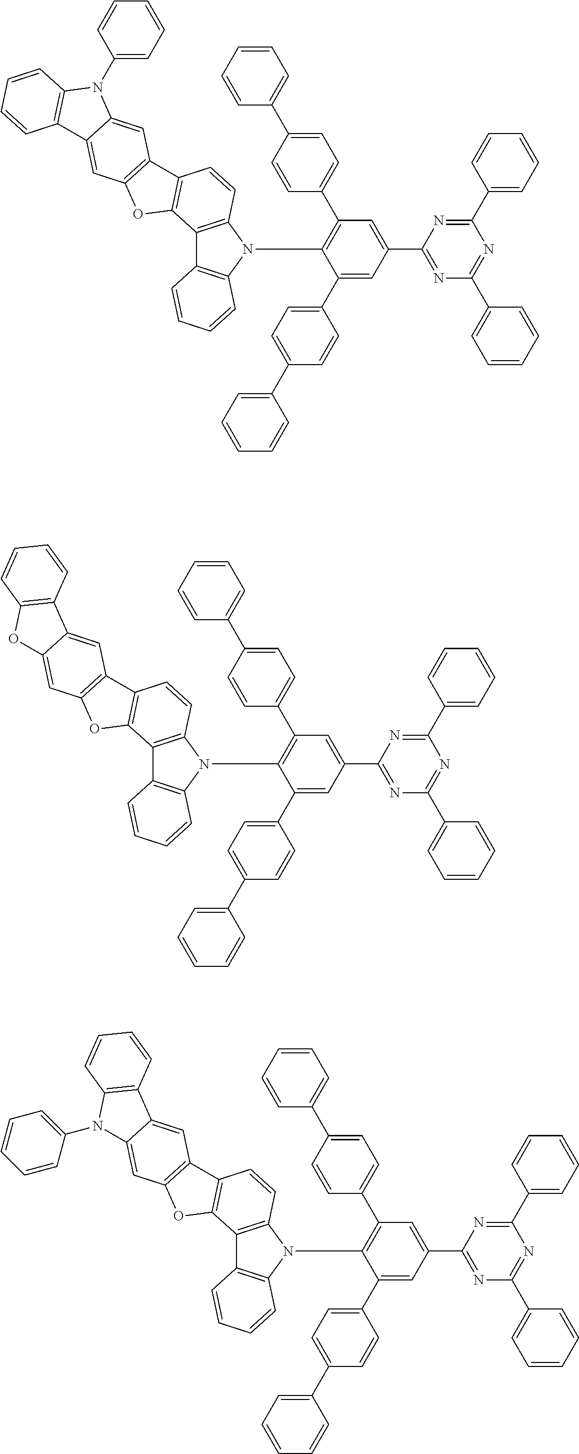 [SMILES: c1ccc(-c2ccc(-c3cc(-c4nc(-c5ccccc5)nc(-c5ccccc5)n4)cc(-c4ccc(-c5ccccc5)cc4)c3-n3c4ccccc4c4c5oc6cc7c8ccccc8n(-c8ccccc8)c7cc6c5ccc43)cc2)cc1 ; c1ccc(-c2ccc(-c3cc(-c4nc(-c5ccccc5)nc(-c5ccccc5)n4)cc(-c4ccc(-c5ccccc5)cc4)c3-n3c4ccccc4c4c5oc6cc7oc8ccccc8c7cc6c5ccc43)cc2)cc1 ; c1ccc(-c2ccc(-c3cc(-c4nc(-c5ccccc5)nc(-c5ccccc5)n4)cc(-c4ccc(-c5ccccc5)cc4)c3-n3c4ccccc4c4c5oc6cc7c(cc6c5ccc43)c3ccccc3n7-c3ccccc3)cc2)cc1]

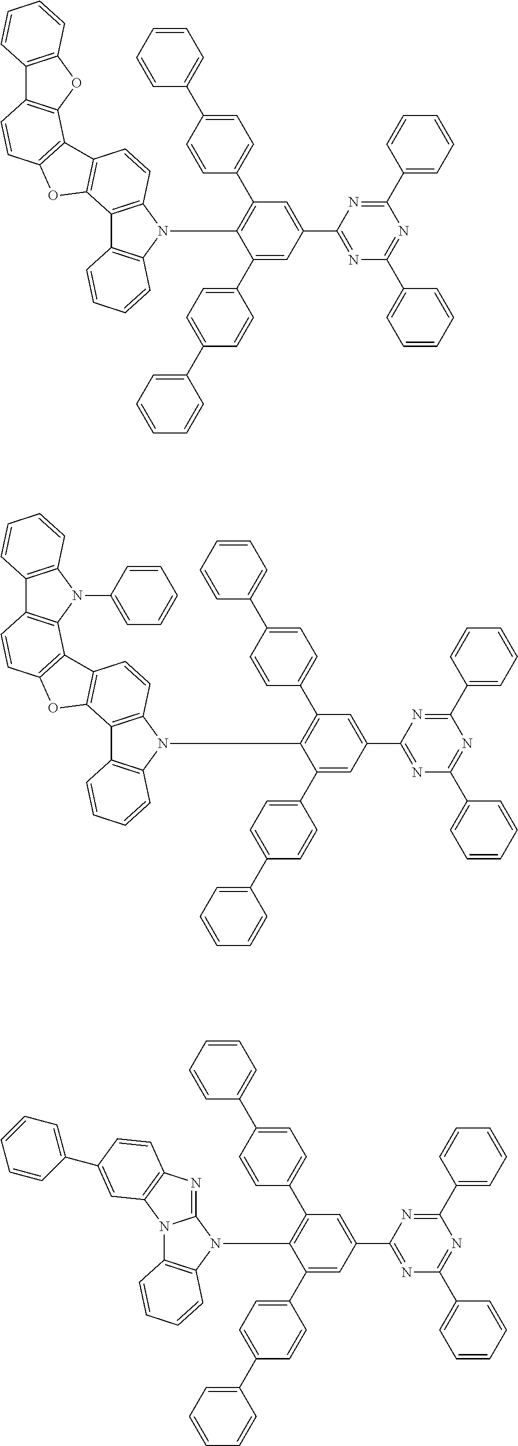 [SMILES: c1ccc(-c2ccc(-c3cc(-c4nc(-c5ccccc5)nc(-c5ccccc5)n4)cc(-c4ccc(-c5ccccc5)cc4)c3-n3c4ccccc4c4c5oc6ccc7c8ccccc8oc7c6c5ccc43)cc2)cc1 ; c1ccc(-c2ccc(-c3cc(-c4nc(-c5ccccc5)nc(-c5ccccc5)n4)cc(-c4ccc(-c5ccccc5)cc4)c3-n3c4ccccc4c4c5oc6ccc7c8ccccc8n(-c8ccccc8)c7c6c5ccc43)cc2)cc1 ; c1ccc(-c2ccc(-c3cc(-c4nc(-c5ccccc5)nc(-c5ccccc5)n4)cc(-c4ccc(-c5ccccc5)cc4)c3-n3c4ccccc4n4c5cc(-c6ccccc6)ccc5nc34)cc2)cc1]

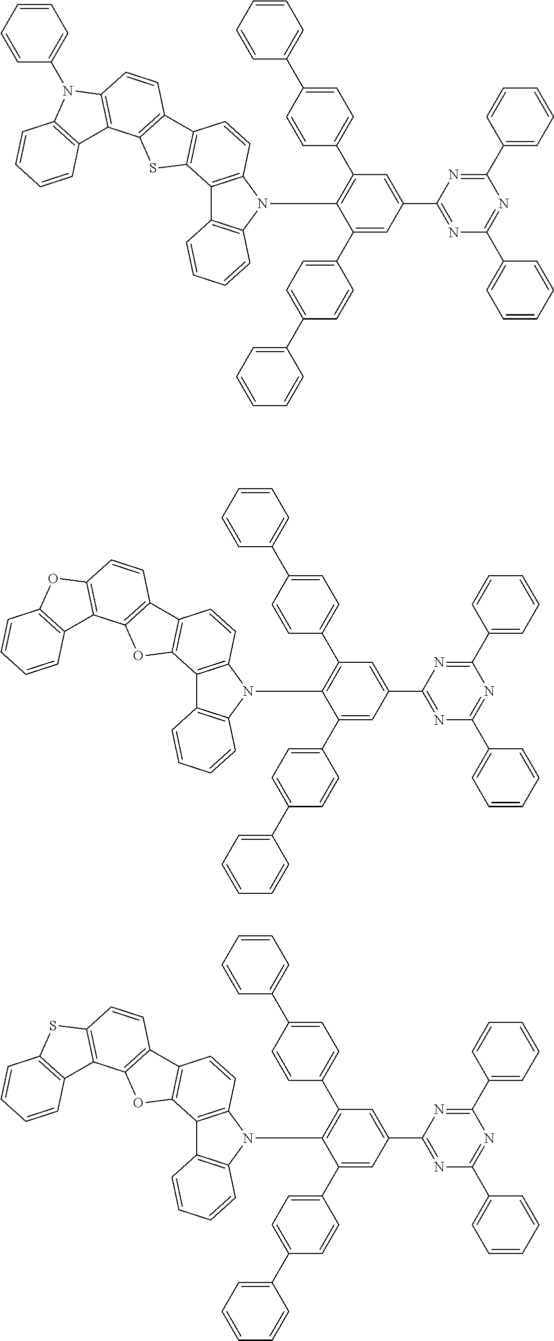

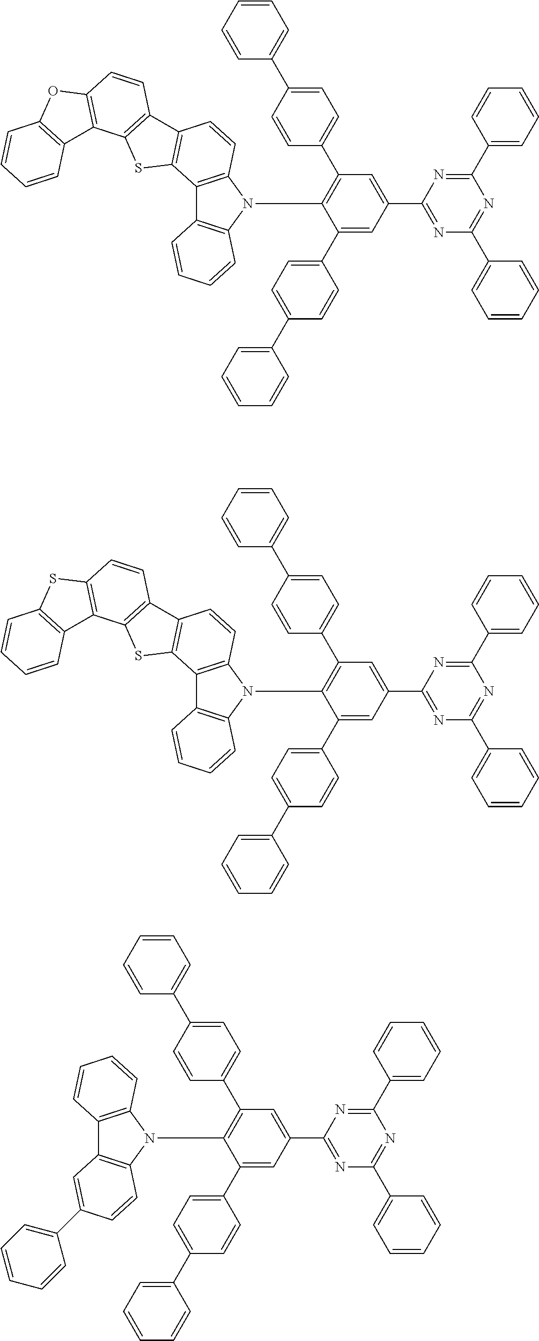 [SMILES: c1ccc(-c2ccc(-c3cc(-c4nc(-c5ccccc5)nc(-c5ccccc5)n4)cc(-c4ccc(-c5ccccc5)cc4)c3-n3c4ccccc4c4c5sc6c(ccc7oc8ccccc8c76)c5ccc43)cc2)cc1 ; c1ccc(-c2ccc(-c3cc(-c4nc(-c5ccccc5)nc(-c5ccccc5)n4)cc(-c4ccc(-c5ccccc5)cc4)c3-n3c4ccccc4c4c5sc6c(ccc7sc8ccccc8c76)c5ccc43)cc2)cc1 ; c1ccc(-c2ccc(-c3cc(-c4nc(-c5ccccc5)nc(-c5ccccc5)n4)cc(-c4ccc(-c5ccccc5)cc4)c3-n3c4ccccc4c4cc(-c5ccccc5)ccc43)cc2)cc1]

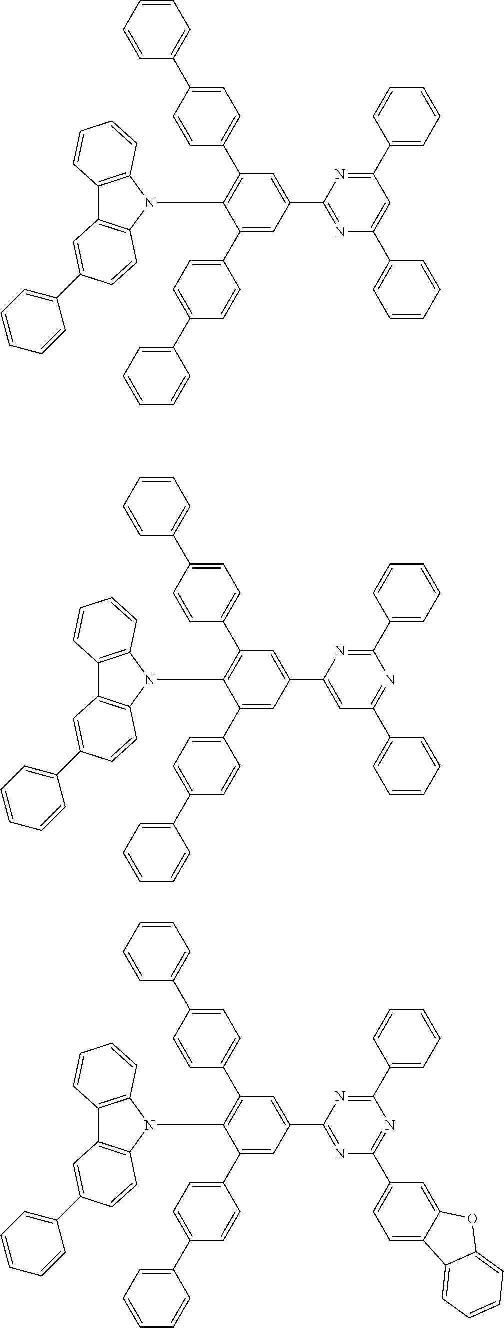

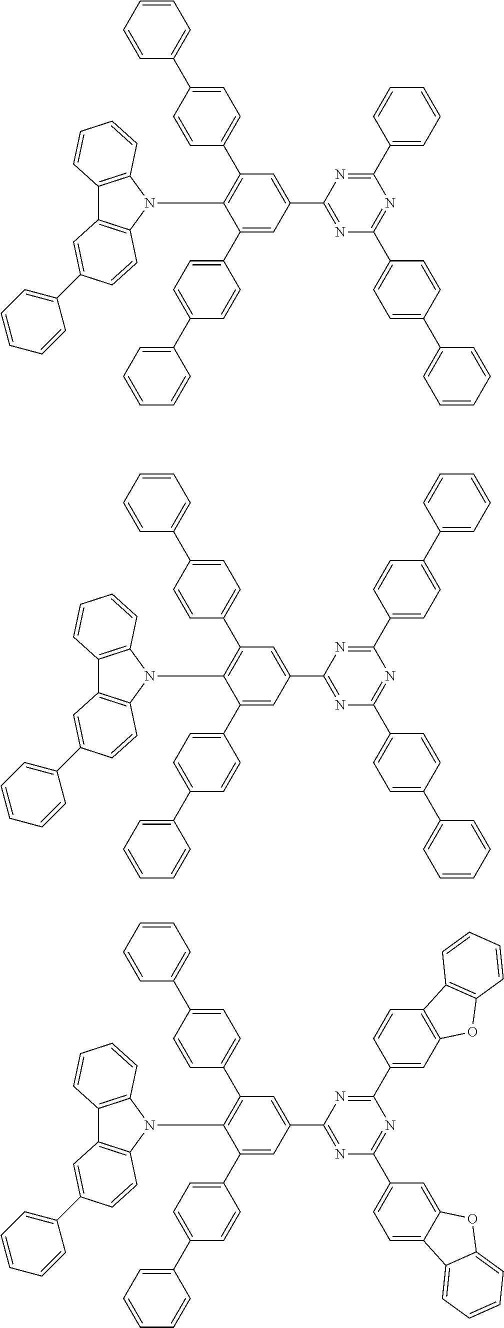

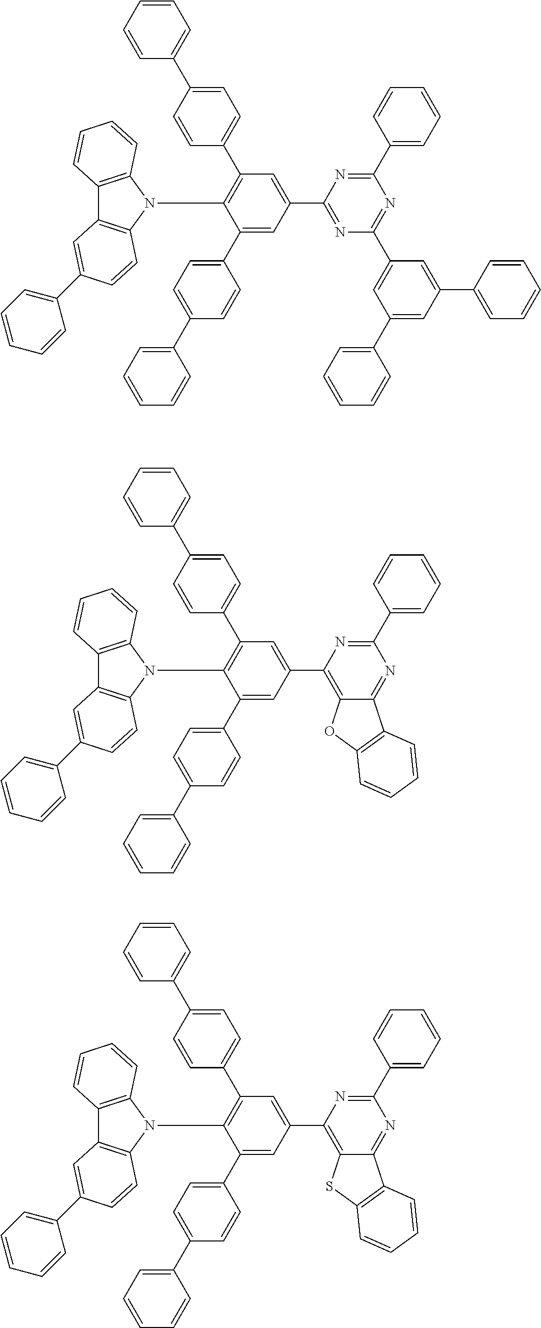 [SMILES: c1ccc(-c2ccc(-c3cc(-c4nc(-c5ccccc5)nc(-c5cc(-c6ccccc6)cc(-c6ccccc6)c5)n4)cc(-c4ccc(-c5ccccc5)cc4)c3-n3c4ccccc4c4cc(-c5ccccc5)ccc43)cc2)cc1 ; c1ccc(-c2ccc(-c3cc(-c4nc(-c5ccccc5)nc5c4oc4ccccc45)cc(-c4ccc(-c5ccccc5)cc4)c3-n3c4ccccc4c4cc(-c5ccccc5)ccc43)cc2)cc1 ; c1ccc(-c2ccc(-c3cc(-c4nc(-c5ccccc5)nc5c4sc4ccccc45)cc(-c4ccc(-c5ccccc5)cc4)c3-n3c4ccccc4c4cc(-c5ccccc5)ccc43)cc2)cc1]

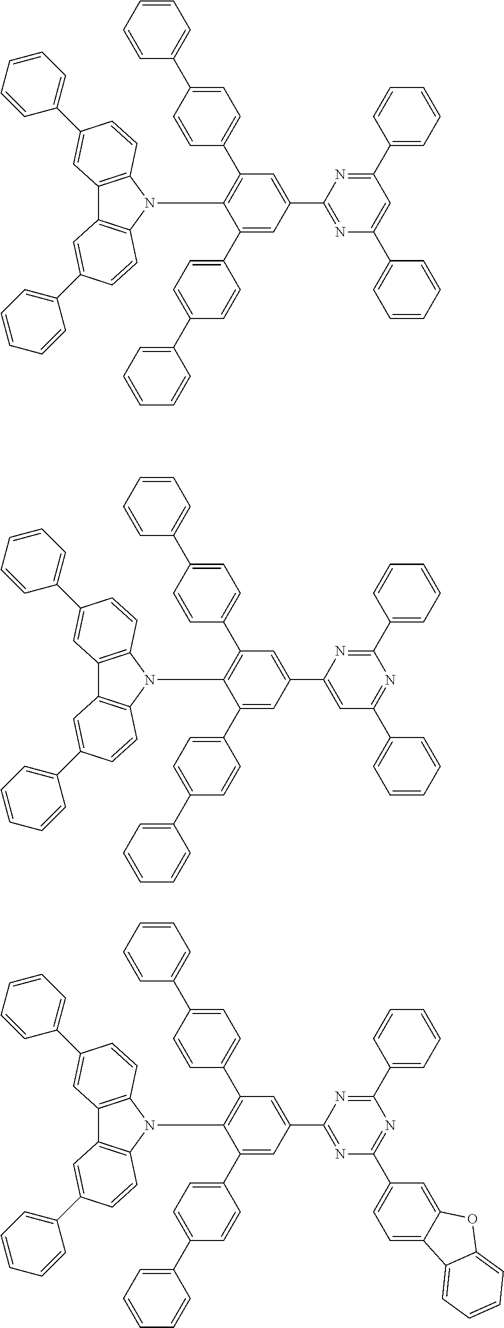

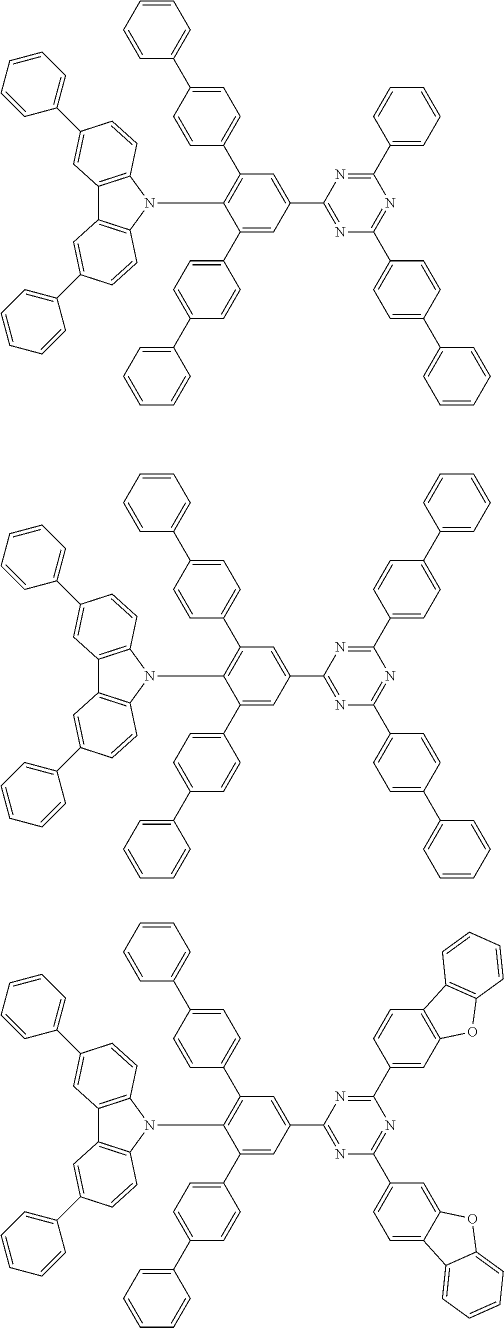

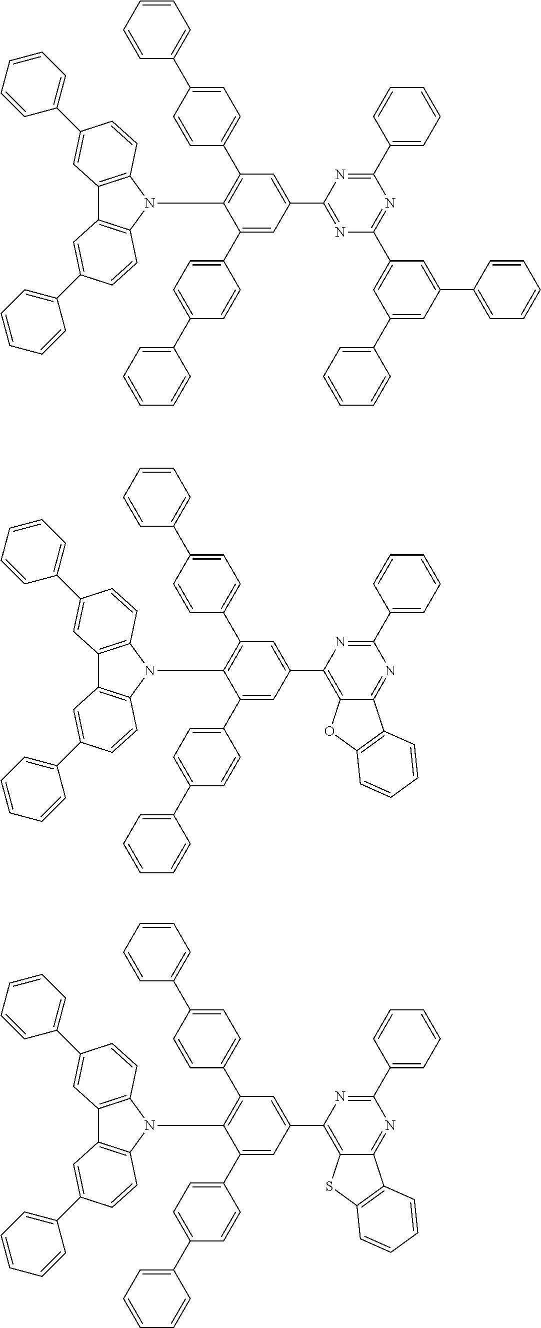 [SMILES: c1ccc(-c2ccc(-c3cc(-c4nc(-c5ccccc5)nc(-c5cc(-c6ccccc6)cc(-c6ccccc6)c5)n4)cc(-c4ccc(-c5ccccc5)cc4)c3-n3c4ccc(-c5ccccc5)cc4c4cc(-c5ccccc5)ccc43)cc2)cc1 ; c1ccc(-c2ccc(-c3cc(-c4nc(-c5ccccc5)nc5c4oc4ccccc45)cc(-c4ccc(-c5ccccc5)cc4)c3-n3c4ccc(-c5ccccc5)cc4c4cc(-c5ccccc5)ccc43)cc2)cc1 ; c1ccc(-c2ccc(-c3cc(-c4nc(-c5ccccc5)nc5c4sc4ccccc45)cc(-c4ccc(-c5ccccc5)cc4)c3-n3c4ccc(-c5ccccc5)cc4c4cc(-c5ccccc5)ccc43)cc2)cc1]

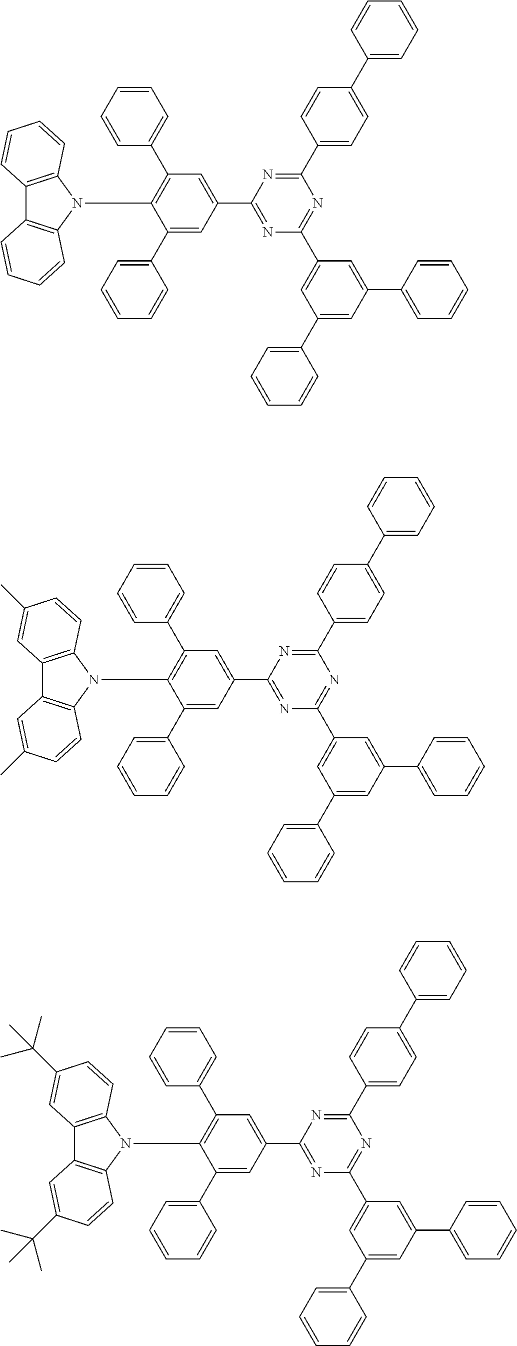 [SMILES: c1ccc(-c2ccc(-c3nc(-c4cc(-c5ccccc5)cc(-c5ccccc5)c4)nc(-c4cc(-c5ccccc5)c(-n5c6ccccc6c6ccccc65)c(-c5ccccc5)c4)n3)cc2)cc1 ; Cc1ccc2c(c1)c1cc(C)ccc1n2-c1c(-c2ccccc2)cc(-c2nc(-c3ccc(-c4ccccc4)cc3)nc(-c3cc(-c4ccccc4)cc(-c4ccccc4)c3)n2)cc1-c1ccccc1 ; CC(C)(C)c1ccc2c(c1)c1cc(C(C)(C)C)ccc1n2-c1c(-c2ccccc2)cc(-c2nc(-c3ccc(-c4ccccc4)cc3)nc(-c3cc(-c4ccccc4)cc(-c4ccccc4)c3)n2)cc1-c1ccccc1]

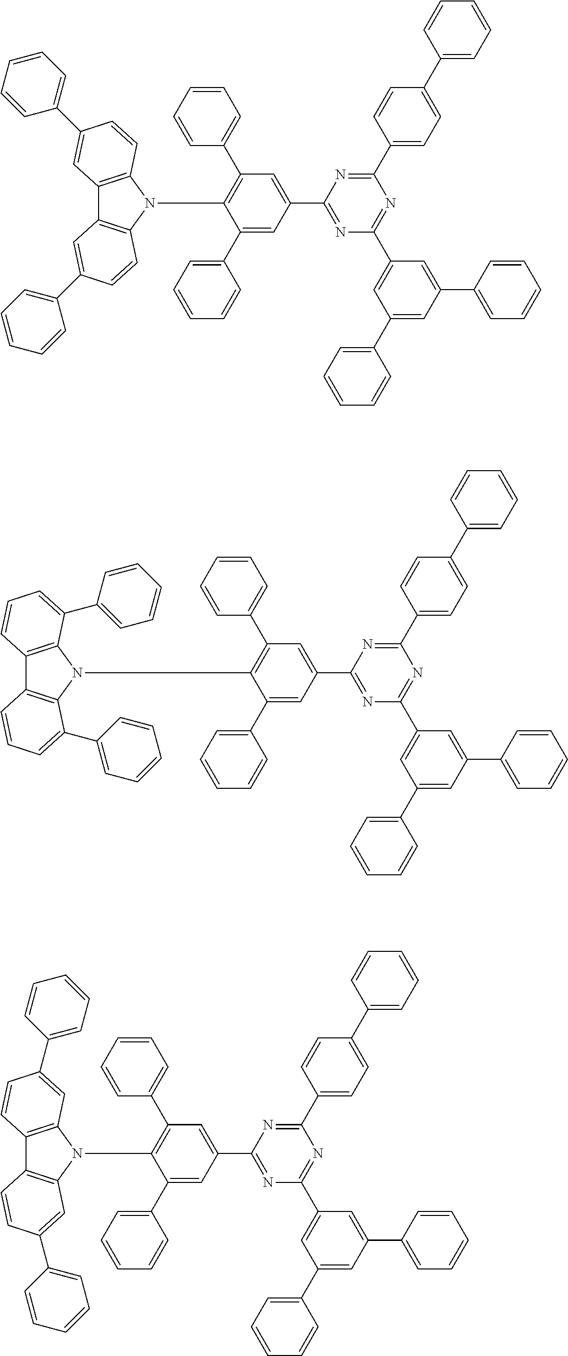 [SMILES: c1ccc(-c2ccc(-c3nc(-c4cc(-c5ccccc5)cc(-c5ccccc5)c4)nc(-c4cc(-c5ccccc5)c(-n5c6ccc(-c7ccccc7)cc6c6cc(-c7ccccc7)ccc65)c(-c5ccccc5)c4)n3)cc2)cc1 ; c1ccc(-c2ccc(-c3nc(-c4cc(-c5ccccc5)cc(-c5ccccc5)c4)nc(-c4cc(-c5ccccc5)c(-n5c6c(-c7ccccc7)cccc6c6cccc(-c7ccccc7)c65)c(-c5ccccc5)c4)n3)cc2)cc1 ; c1ccc(-c2ccc(-c3nc(-c4cc(-c5ccccc5)cc(-c5ccccc5)c4)nc(-c4cc(-c5ccccc5)c(-n5c6cc(-c7ccccc7)ccc6c6ccc(-c7ccccc7)cc65)c(-c5ccccc5)c4)n3)cc2)cc1]

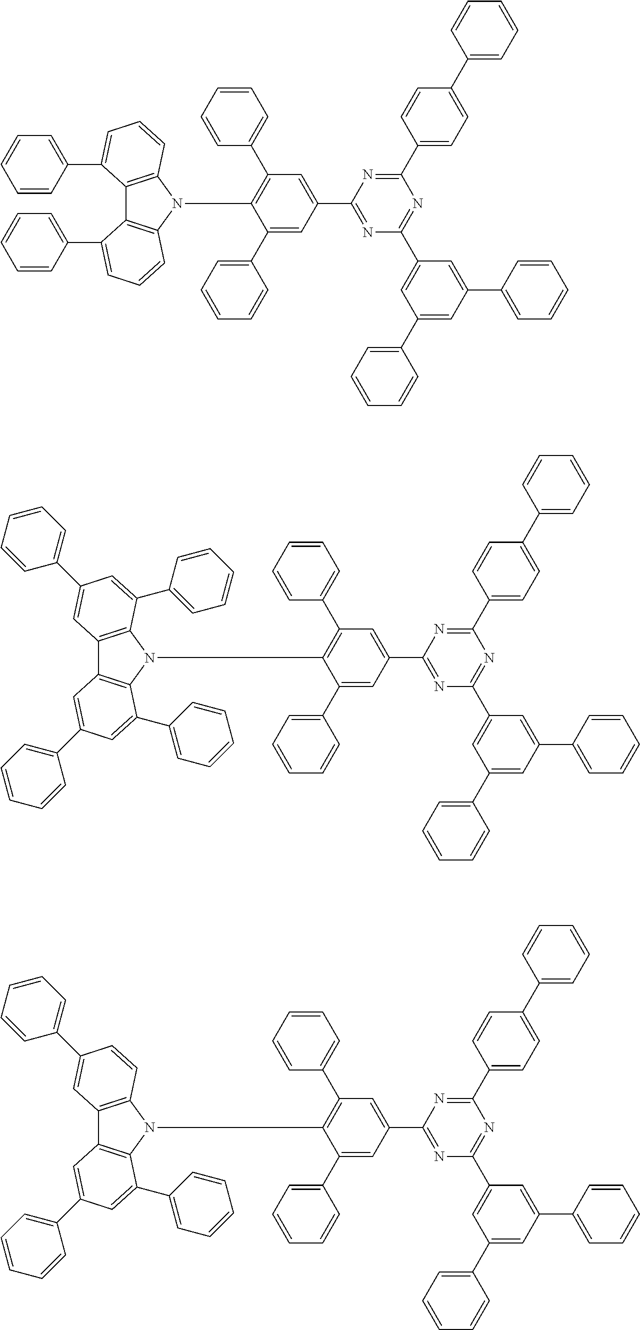 [SMILES: c1ccc(-c2ccc(-c3nc(-c4cc(-c5ccccc5)cc(-c5ccccc5)c4)nc(-c4cc(-c5ccccc5)c(-n5c6cccc(-c7ccccc7)c6c6c(-c7ccccc7)cccc65)c(-c5ccccc5)c4)n3)cc2)cc1 ; c1ccc(-c2ccc(-c3nc(-c4cc(-c5ccccc5)cc(-c5ccccc5)c4)nc(-c4cc(-c5ccccc5)c(-n5c6c(-c7ccccc7)cc(-c7ccccc7)cc6c6cc(-c7ccccc7)cc(-c7ccccc7)c65)c(-c5ccccc5)c4)n3)cc2)cc1 ; c1ccc(-c2ccc(-c3nc(-c4cc(-c5ccccc5)cc(-c5ccccc5)c4)nc(-c4cc(-c5ccccc5)c(-n5c6ccc(-c7ccccc7)cc6c6cc(-c7ccccc7)cc(-c7ccccc7)c65)c(-c5ccccc5)c4)n3)cc2)cc1]

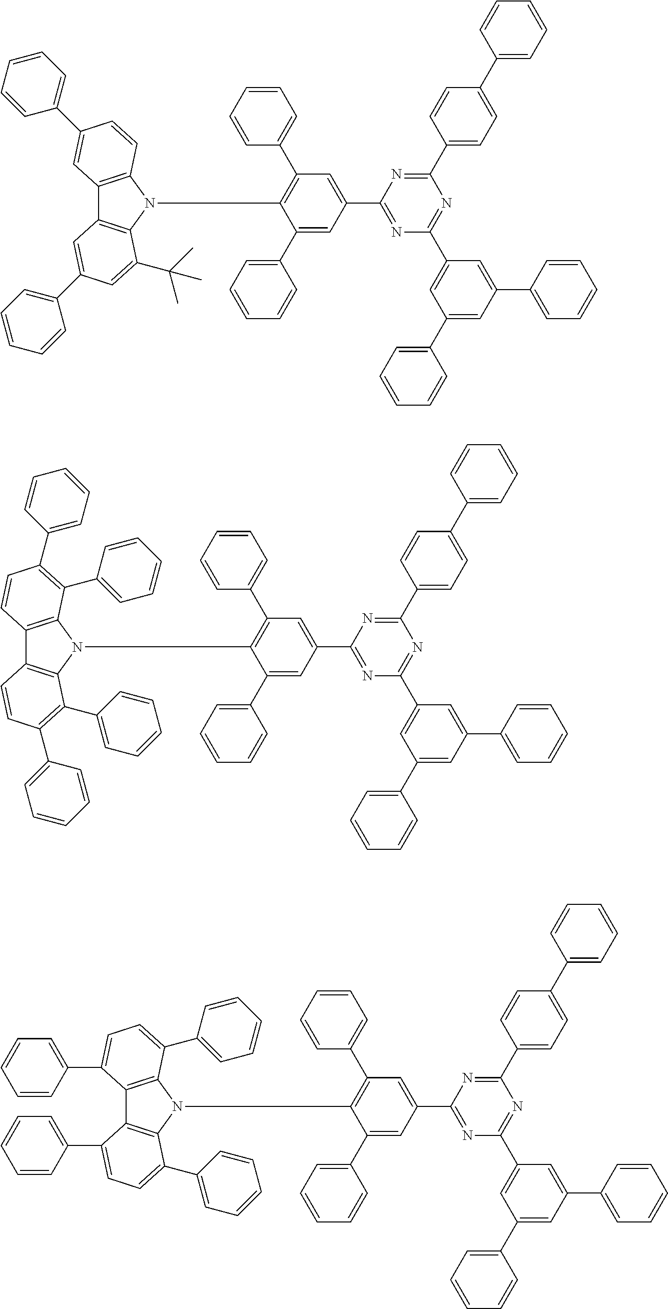 [SMILES: CC(C)(C)c1cc(-c2ccccc2)cc2c3cc(-c4ccccc4)ccc3n(-c3c(-c4ccccc4)cc(-c4nc(-c5ccc(-c6ccccc6)cc5)nc(-c5cc(-c6ccccc6)cc(-c6ccccc6)c5)n4)cc3-c3ccccc3)c12 ; c1ccc(-c2ccc(-c3nc(-c4cc(-c5ccccc5)cc(-c5ccccc5)c4)nc(-c4cc(-c5ccccc5)c(-n5c6c(-c7ccccc7)c(-c7ccccc7)ccc6c6ccc(-c7ccccc7)c(-c7ccccc7)c65)c(-c5ccccc5)c4)n3)cc2)cc1 ; c1ccc(-c2ccc(-c3nc(-c4cc(-c5ccccc5)cc(-c5ccccc5)c4)nc(-c4cc(-c5ccccc5)c(-n5c6c(-c7ccccc7)ccc(-c7ccccc7)c6c6c(-c7ccccc7)ccc(-c7ccccc7)c65)c(-c5ccccc5)c4)n3)cc2)cc1]

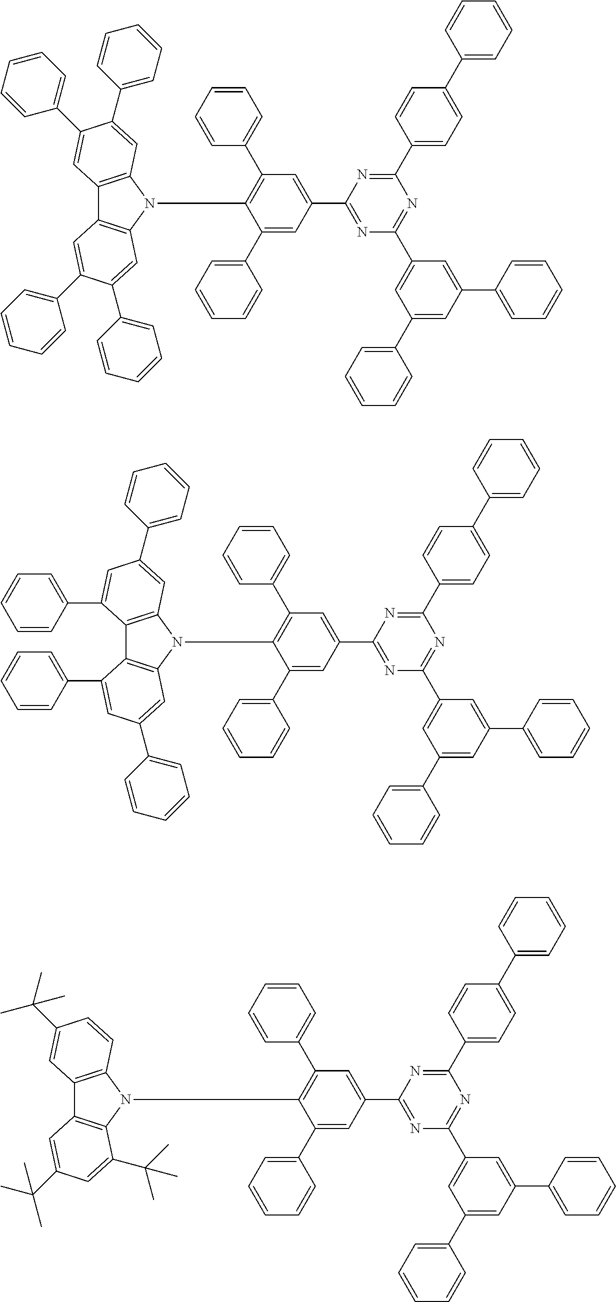 [SMILES: c1ccc(-c2ccc(-c3nc(-c4cc(-c5ccccc5)cc(-c5ccccc5)c4)nc(-c4cc(-c5ccccc5)c(-n5c6cc(-c7ccccc7)c(-c7ccccc7)cc6c6cc(-c7ccccc7)c(-c7ccccc7)cc65)c(-c5ccccc5)c4)n3)cc2)cc1 ; c1ccc(-c2ccc(-c3nc(-c4cc(-c5ccccc5)cc(-c5ccccc5)c4)nc(-c4cc(-c5ccccc5)c(-n5c6cc(-c7ccccc7)cc(-c7ccccc7)c6c6c(-c7ccccc7)cc(-c7ccccc7)cc65)c(-c5ccccc5)c4)n3)cc2)cc1 ; CC(C)(C)c1ccc2c(c1)c1cc(C(C)(C)C)cc(C(C)(C)C)c1n2-c1c(-c2ccccc2)cc(-c2nc(-c3ccc(-c4ccccc4)cc3)nc(-c3cc(-c4ccccc4)cc(-c4ccccc4)c3)n2)cc1-c1ccccc1]

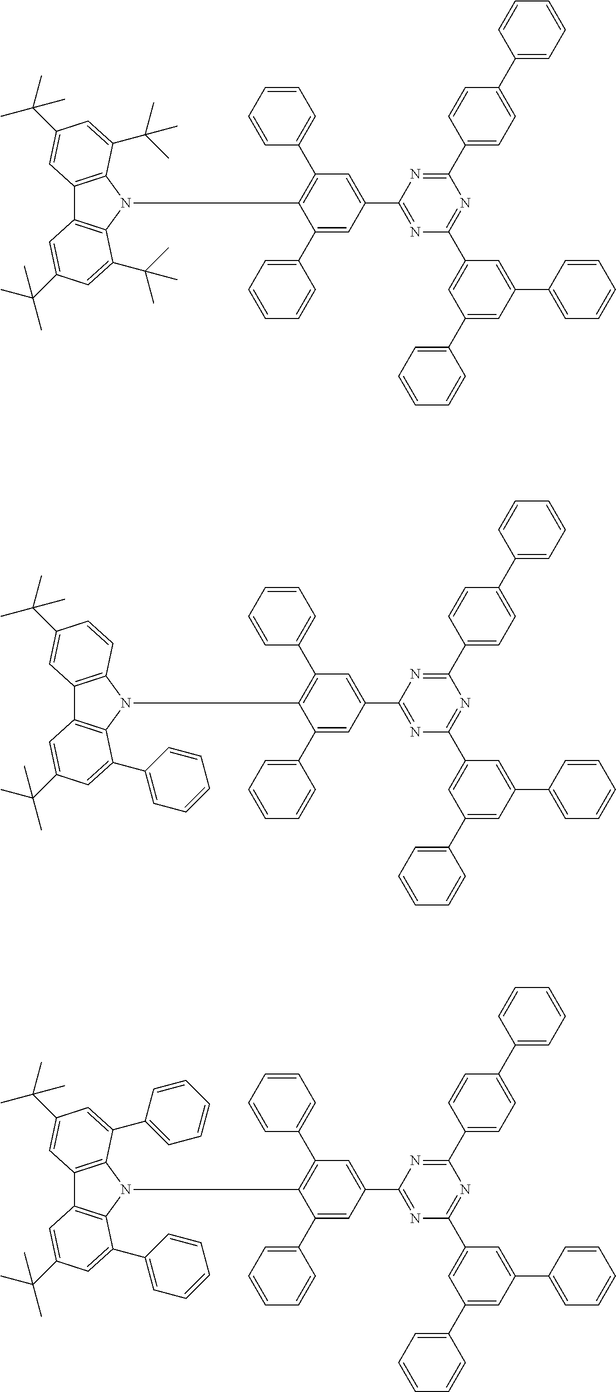 [SMILES: CC(C)(C)c1cc(C(C)(C)C)c2c(c1)c1cc(C(C)(C)C)cc(C(C)(C)C)c1n2-c1c(-c2ccccc2)cc(-c2nc(-c3ccc(-c4ccccc4)cc3)nc(-c3cc(-c4ccccc4)cc(-c4ccccc4)c3)n2)cc1-c1ccccc1 ; CC(C)(C)c1ccc2c(c1)c1cc(C(C)(C)C)cc(-c3ccccc3)c1n2-c1c(-c2ccccc2)cc(-c2nc(-c3ccc(-c4ccccc4)cc3)nc(-c3cc(-c4ccccc4)cc(-c4ccccc4)c3)n2)cc1-c1ccccc1 ; CC(C)(C)c1cc(-c2ccccc2)c2c(c1)c1cc(C(C)(C)C)cc(-c3ccccc3)c1n2-c1c(-c2ccccc2)cc(-c2nc(-c3ccc(-c4ccccc4)cc3)nc(-c3cc(-c4ccccc4)cc(-c4ccccc4)c3)n2)cc1-c1ccccc1]

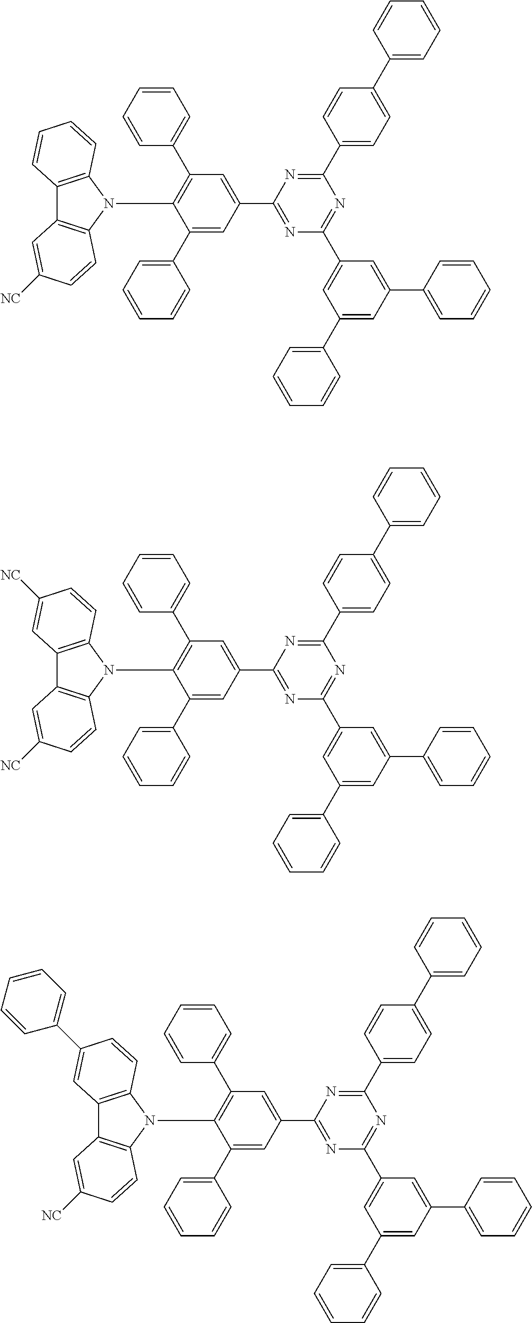 [SMILES: N#Cc1ccc2c(c1)c1ccccc1n2-c1c(-c2ccccc2)cc(-c2nc(-c3ccc(-c4ccccc4)cc3)nc(-c3cc(-c4ccccc4)cc(-c4ccccc4)c3)n2)cc1-c1ccccc1 ; N#Cc1ccc2c(c1)c1cc(C#N)ccc1n2-c1c(-c2ccccc2)cc(-c2nc(-c3ccc(-c4ccccc4)cc3)nc(-c3cc(-c4ccccc4)cc(-c4ccccc4)c3)n2)cc1-c1ccccc1 ; N#Cc1ccc2c(c1)c1cc(-c3ccccc3)ccc1n2-c1c(-c2ccccc2)cc(-c2nc(-c3ccc(-c4ccccc4)cc3)nc(-c3cc(-c4ccccc4)cc(-c4ccccc4)c3)n2)cc1-c1ccccc1]

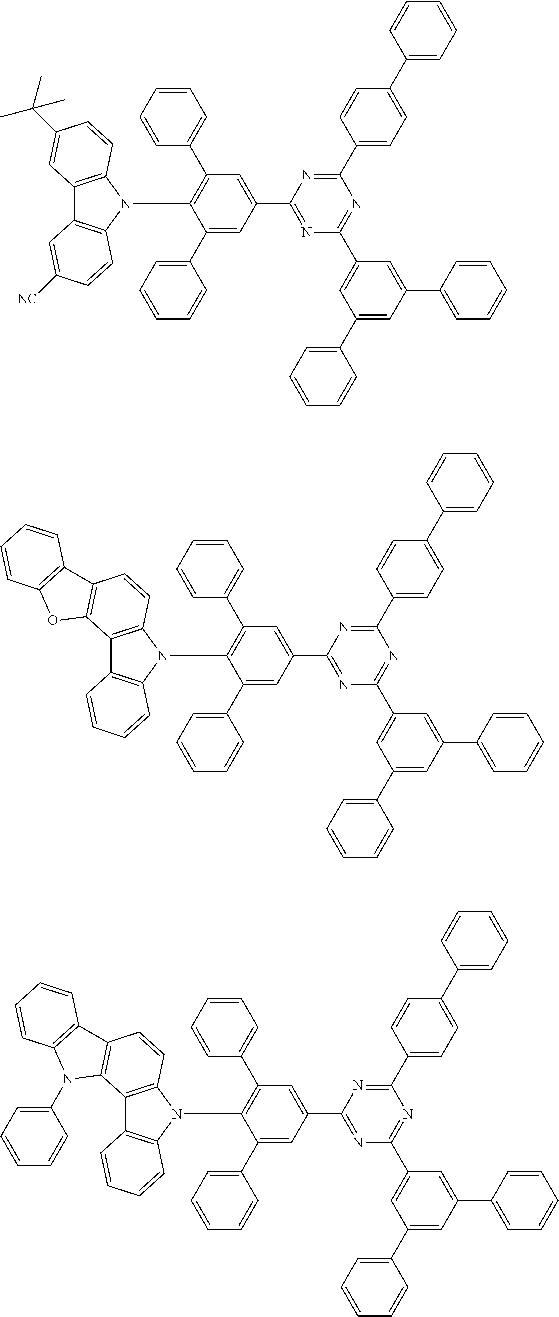 [SMILES: CC(C)(C)c1ccc2c(c1)c1cc(C#N)ccc1n2-c1c(-c2ccccc2)cc(-c2nc(-c3ccc(-c4ccccc4)cc3)nc(-c3cc(-c4ccccc4)cc(-c4ccccc4)c3)n2)cc1-c1ccccc1 ; c1ccc(-c2ccc(-c3nc(-c4cc(-c5ccccc5)cc(-c5ccccc5)c4)nc(-c4cc(-c5ccccc5)c(-n5c6ccccc6c6c7oc8ccccc8c7ccc65)c(-c5ccccc5)c4)n3)cc2)cc1 ; c1ccc(-c2ccc(-c3nc(-c4cc(-c5ccccc5)cc(-c5ccccc5)c4)nc(-c4cc(-c5ccccc5)c(-n5c6ccccc6c6c5ccc5c7ccccc7n(-c7ccccc7)c56)c(-c5ccccc5)c4)n3)cc2)cc1]

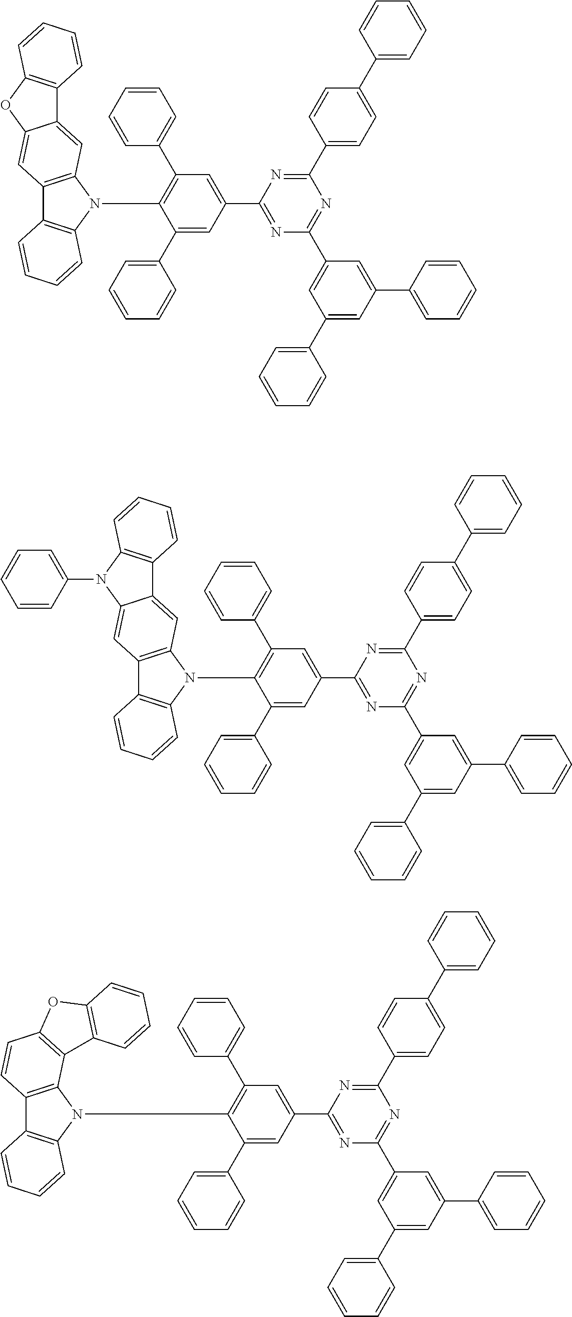 [SMILES: c1ccc(-c2ccc(-c3nc(-c4cc(-c5ccccc5)cc(-c5ccccc5)c4)nc(-c4cc(-c5ccccc5)c(-n5c6ccccc6c6cc7oc8ccccc8c7cc65)c(-c5ccccc5)c4)n3)cc2)cc1 ; c1ccc(-c2ccc(-c3nc(-c4cc(-c5ccccc5)cc(-c5ccccc5)c4)nc(-c4cc(-c5ccccc5)c(-n5c6ccccc6c6cc7c(cc65)c5ccccc5n7-c5ccccc5)c(-c5ccccc5)c4)n3)cc2)cc1 ; c1ccc(-c2ccc(-c3nc(-c4cc(-c5ccccc5)cc(-c5ccccc5)c4)nc(-c4cc(-c5ccccc5)c(-n5c6ccccc6c6ccc7oc8ccccc8c7c65)c(-c5ccccc5)c4)n3)cc2)cc1]

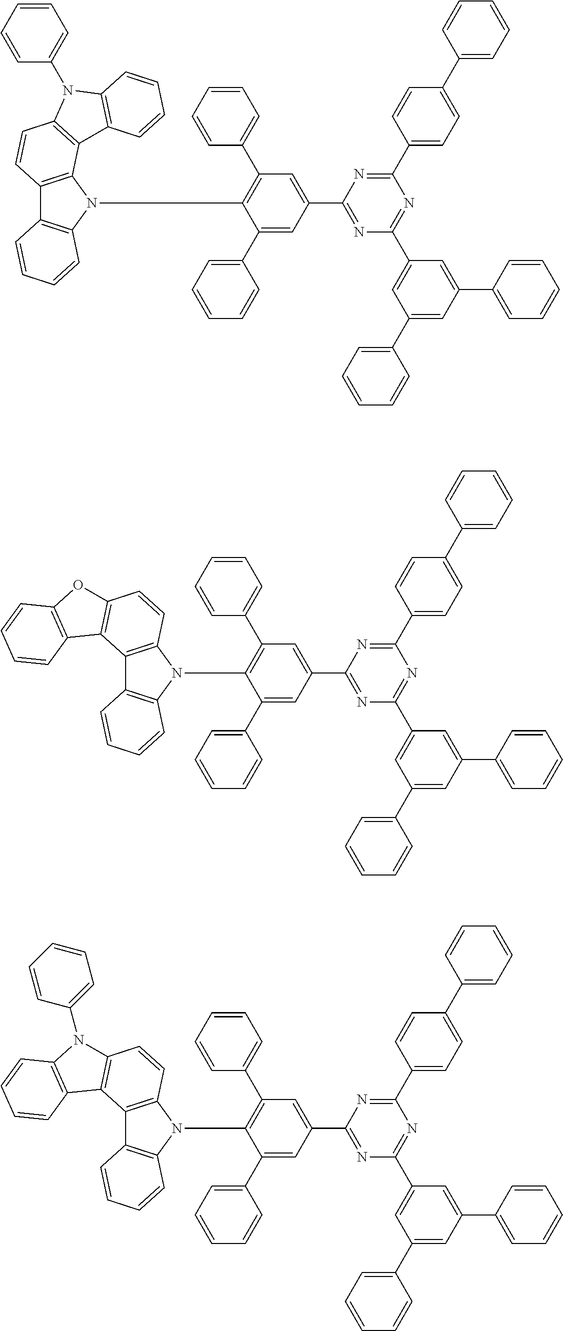 [SMILES: c1ccc(-c2ccc(-c3nc(-c4cc(-c5ccccc5)cc(-c5ccccc5)c4)nc(-c4cc(-c5ccccc5)c(-n5c6ccccc6c6ccc7c(c8ccccc8n7-c7ccccc7)c65)c(-c5ccccc5)c4)n3)cc2)cc1 ; c1ccc(-c2ccc(-c3nc(-c4cc(-c5ccccc5)cc(-c5ccccc5)c4)nc(-c4cc(-c5ccccc5)c(-n5c6ccccc6c6c7c(ccc65)oc5ccccc57)c(-c5ccccc5)c4)n3)cc2)cc1 ; c1ccc(-c2ccc(-c3nc(-c4cc(-c5ccccc5)cc(-c5ccccc5)c4)nc(-c4cc(-c5ccccc5)c(-n5c6ccccc6c6c7c8ccccc8n(-c8ccccc8)c7ccc65)c(-c5ccccc5)c4)n3)cc2)cc1]

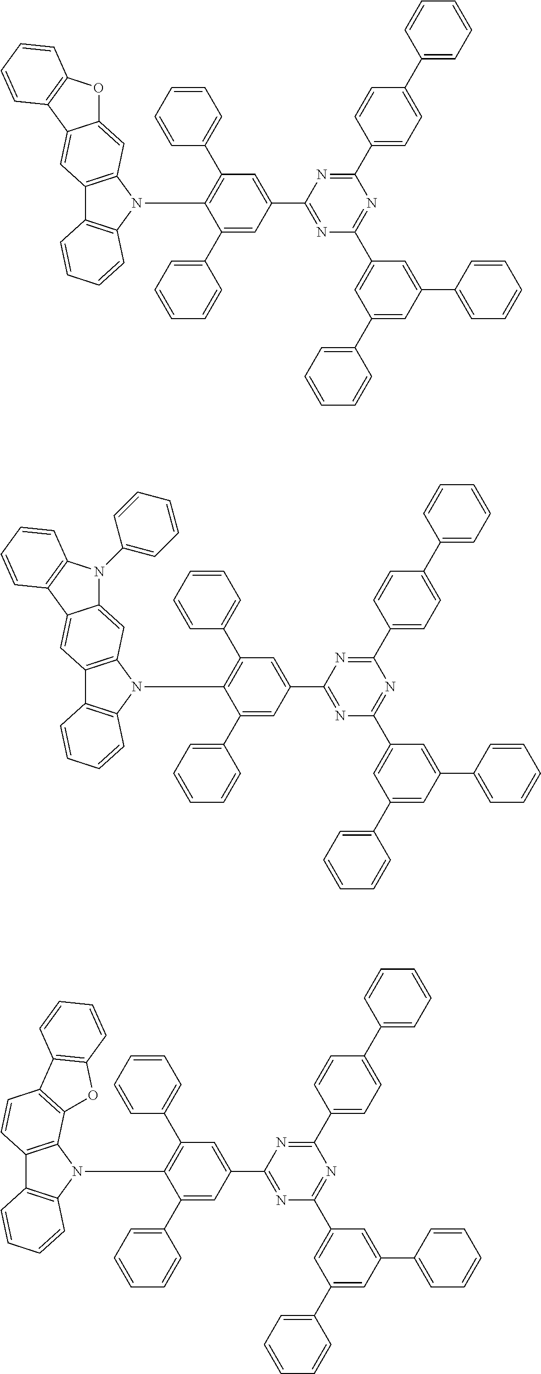 [SMILES: c1ccc(-c2ccc(-c3nc(-c4cc(-c5ccccc5)cc(-c5ccccc5)c4)nc(-c4cc(-c5ccccc5)c(-n5c6ccccc6c6cc7c(cc65)oc5ccccc57)c(-c5ccccc5)c4)n3)cc2)cc1 ; c1ccc(-c2ccc(-c3nc(-c4cc(-c5ccccc5)cc(-c5ccccc5)c4)nc(-c4cc(-c5ccccc5)c(-n5c6ccccc6c6cc7c8ccccc8n(-c8ccccc8)c7cc65)c(-c5ccccc5)c4)n3)cc2)cc1 ; c1ccc(-c2ccc(-c3nc(-c4cc(-c5ccccc5)cc(-c5ccccc5)c4)nc(-c4cc(-c5ccccc5)c(-n5c6ccccc6c6ccc7c8ccccc8oc7c65)c(-c5ccccc5)c4)n3)cc2)cc1]

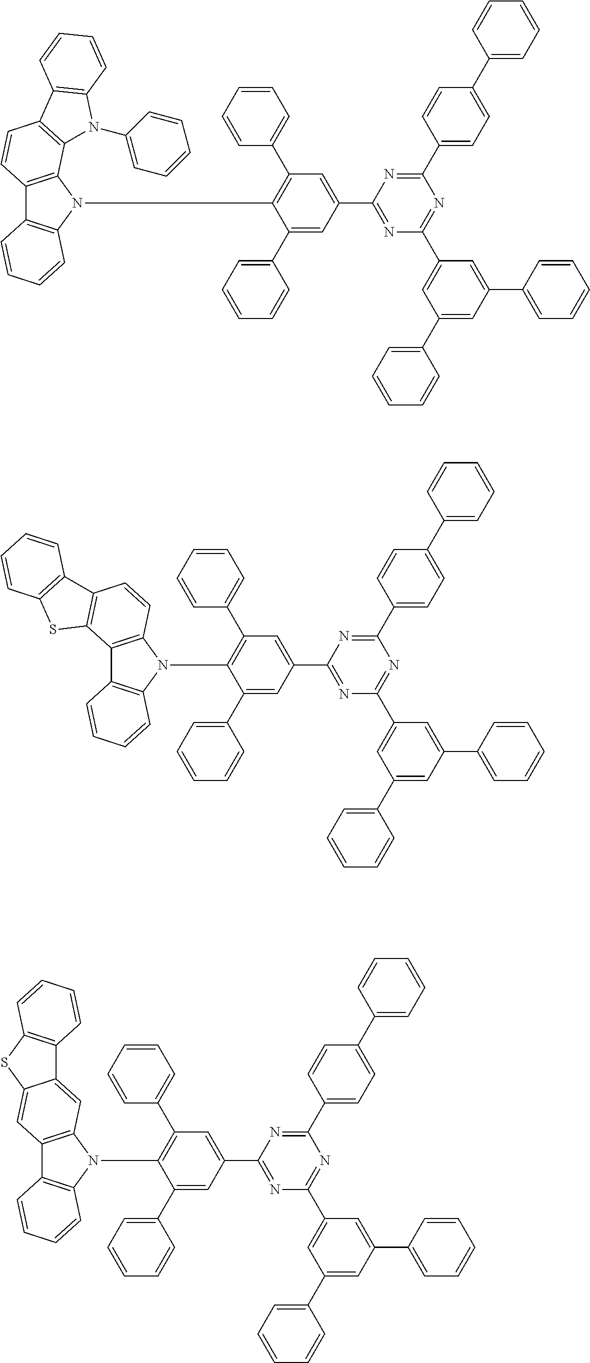 [SMILES: c1ccc(-c2ccc(-c3nc(-c4cc(-c5ccccc5)cc(-c5ccccc5)c4)nc(-c4cc(-c5ccccc5)c(-n5c6ccccc6c6ccc7c8ccccc8n(-c8ccccc8)c7c65)c(-c5ccccc5)c4)n3)cc2)cc1 ; c1ccc(-c2ccc(-c3nc(-c4cc(-c5ccccc5)cc(-c5ccccc5)c4)nc(-c4cc(-c5ccccc5)c(-n5c6ccccc6c6c7sc8ccccc8c7ccc65)c(-c5ccccc5)c4)n3)cc2)cc1 ; c1ccc(-c2ccc(-c3nc(-c4cc(-c5ccccc5)cc(-c5ccccc5)c4)nc(-c4cc(-c5ccccc5)c(-n5c6ccccc6c6cc7sc8ccccc8c7cc65)c(-c5ccccc5)c4)n3)cc2)cc1]

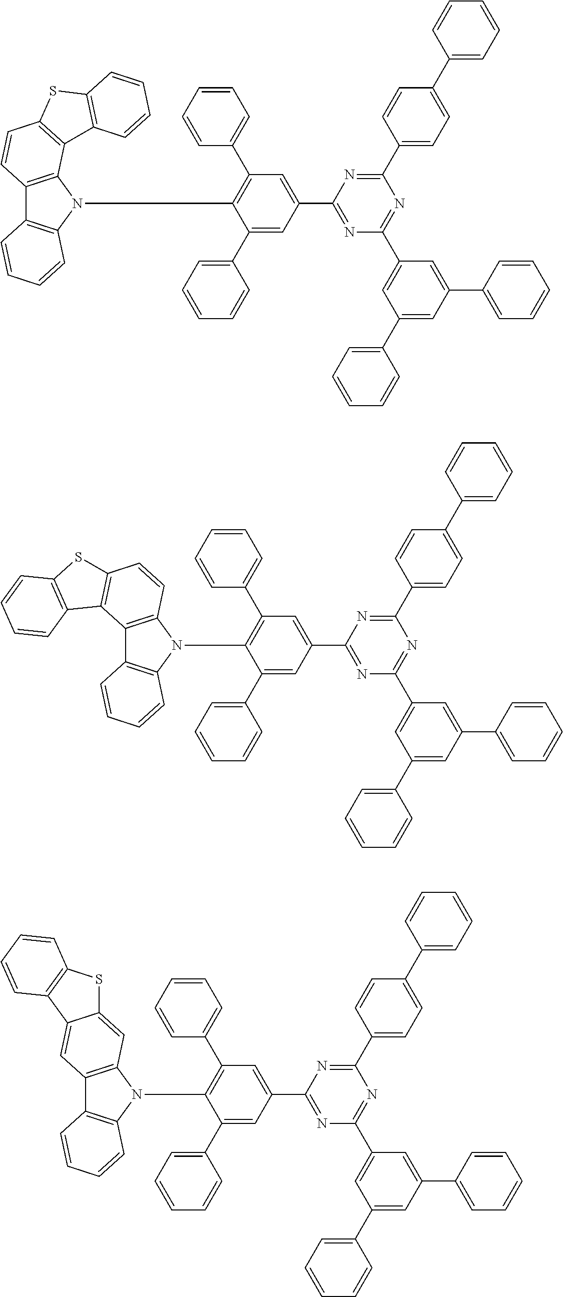 [SMILES: c1ccc(-c2ccc(-c3nc(-c4cc(-c5ccccc5)cc(-c5ccccc5)c4)nc(-c4cc(-c5ccccc5)c(-n5c6ccccc6c6ccc7sc8ccccc8c7c65)c(-c5ccccc5)c4)n3)cc2)cc1 ; c1ccc(-c2ccc(-c3nc(-c4cc(-c5ccccc5)cc(-c5ccccc5)c4)nc(-c4cc(-c5ccccc5)c(-n5c6ccccc6c6c7c(ccc65)sc5ccccc57)c(-c5ccccc5)c4)n3)cc2)cc1 ; c1ccc(-c2ccc(-c3nc(-c4cc(-c5ccccc5)cc(-c5ccccc5)c4)nc(-c4cc(-c5ccccc5)c(-n5c6ccccc6c6cc7c(cc65)sc5ccccc57)c(-c5ccccc5)c4)n3)cc2)cc1]

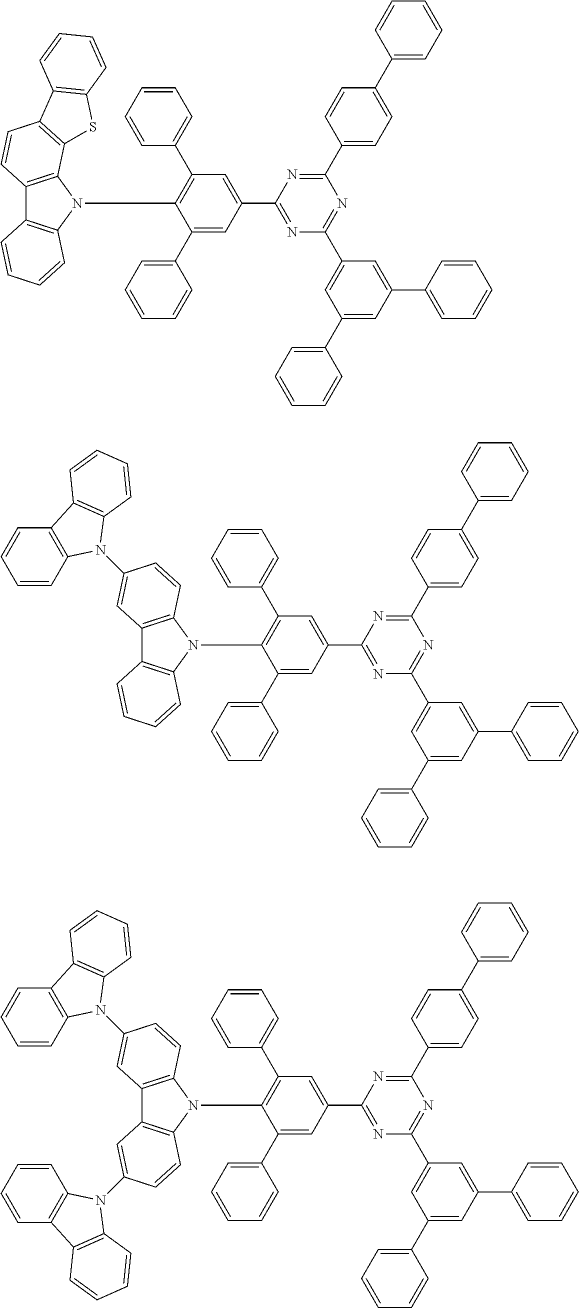 [SMILES: c1ccc(-c2ccc(-c3nc(-c4cc(-c5ccccc5)cc(-c5ccccc5)c4)nc(-c4cc(-c5ccccc5)c(-n5c6ccccc6c6ccc7c8ccccc8sc7c65)c(-c5ccccc5)c4)n3)cc2)cc1 ; c1ccc(-c2ccc(-c3nc(-c4cc(-c5ccccc5)cc(-c5ccccc5)c4)nc(-c4cc(-c5ccccc5)c(-n5c6ccccc6c6cc(-n7c8ccccc8c8ccccc87)ccc65)c(-c5ccccc5)c4)n3)cc2)cc1 ; c1ccc(-c2ccc(-c3nc(-c4cc(-c5ccccc5)cc(-c5ccccc5)c4)nc(-c4cc(-c5ccccc5)c(-n5c6ccc(-n7c8ccccc8c8ccccc87)cc6c6cc(-n7c8ccccc8c8ccccc87)ccc65)c(-c5ccccc5)c4)n3)cc2)cc1]

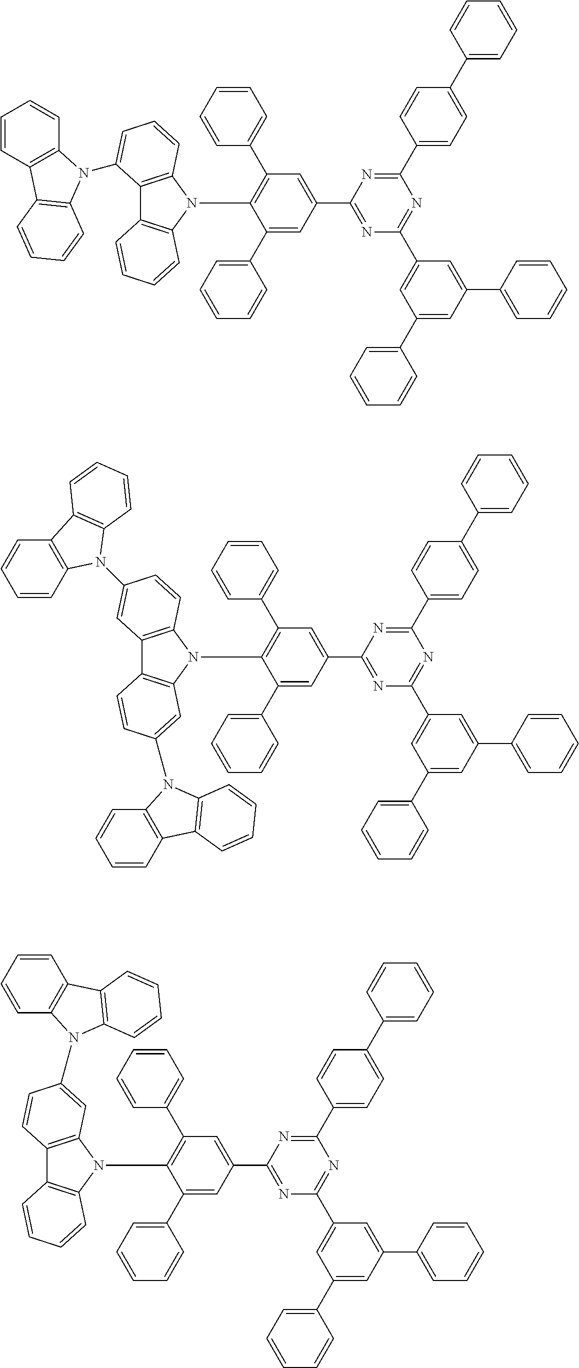 [SMILES: c1ccc(-c2ccc(-c3nc(-c4cc(-c5ccccc5)cc(-c5ccccc5)c4)nc(-c4cc(-c5ccccc5)c(-n5c6ccccc6c6c(-n7c8ccccc8c8ccccc87)cccc65)c(-c5ccccc5)c4)n3)cc2)cc1 ; c1ccc(-c2ccc(-c3nc(-c4cc(-c5ccccc5)cc(-c5ccccc5)c4)nc(-c4cc(-c5ccccc5)c(-n5c6ccc(-n7c8ccccc8c8ccccc87)cc6c6ccc(-n7c8ccccc8c8ccccc87)cc65)c(-c5ccccc5)c4)n3)cc2)cc1 ; c1ccc(-c2ccc(-c3nc(-c4cc(-c5ccccc5)cc(-c5ccccc5)c4)nc(-c4cc(-c5ccccc5)c(-n5c6ccccc6c6ccc(-n7c8ccccc8c8ccccc87)cc65)c(-c5ccccc5)c4)n3)cc2)cc1]

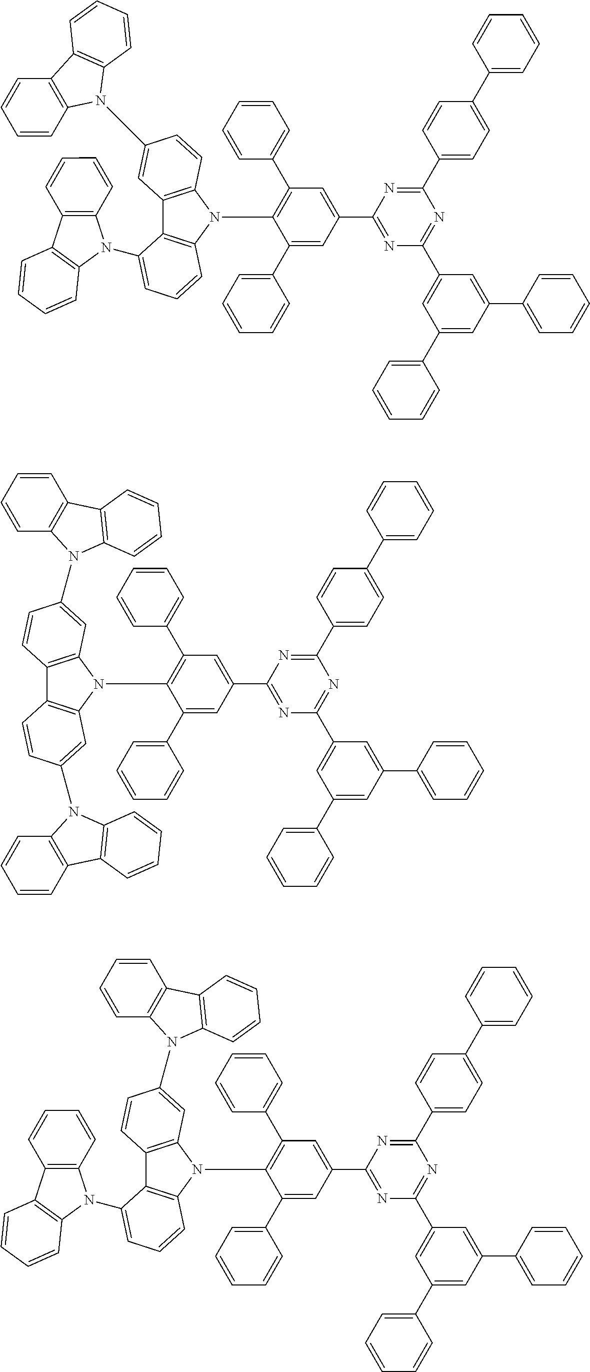 [SMILES: c1ccc(-c2ccc(-c3nc(-c4cc(-c5ccccc5)cc(-c5ccccc5)c4)nc(-c4cc(-c5ccccc5)c(-n5c6ccc(-n7c8ccccc8c8ccccc87)cc6c6c(-n7c8ccccc8c8ccccc87)cccc65)c(-c5ccccc5)c4)n3)cc2)cc1 ; c1ccc(-c2ccc(-c3nc(-c4cc(-c5ccccc5)cc(-c5ccccc5)c4)nc(-c4cc(-c5ccccc5)c(-n5c6cc(-n7c8ccccc8c8ccccc87)ccc6c6ccc(-n7c8ccccc8c8ccccc87)cc65)c(-c5ccccc5)c4)n3)cc2)cc1 ; c1ccc(-c2ccc(-c3nc(-c4cc(-c5ccccc5)cc(-c5ccccc5)c4)nc(-c4cc(-c5ccccc5)c(-n5c6cc(-n7c8ccccc8c8ccccc87)ccc6c6c(-n7c8ccccc8c8ccccc87)cccc65)c(-c5ccccc5)c4)n3)cc2)cc1]

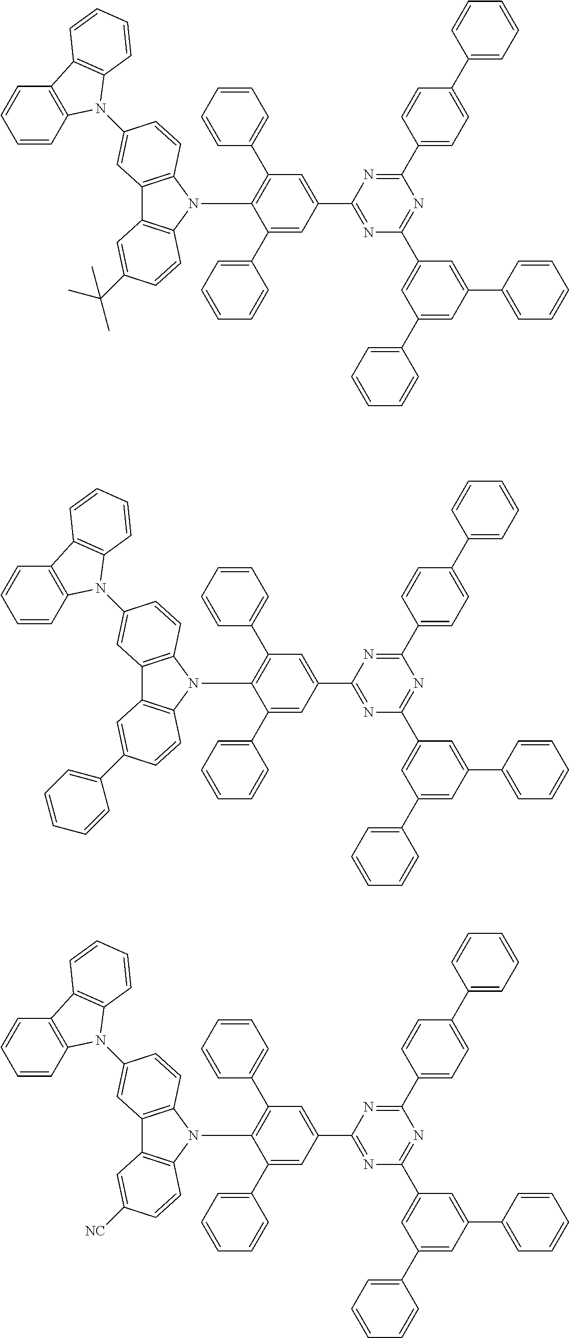 [SMILES: CC(C)(C)c1ccc2c(c1)c1cc(-n3c4ccccc4c4ccccc43)ccc1n2-c1c(-c2ccccc2)cc(-c2nc(-c3ccc(-c4ccccc4)cc3)nc(-c3cc(-c4ccccc4)cc(-c4ccccc4)c3)n2)cc1-c1ccccc1 ; c1ccc(-c2ccc(-c3nc(-c4cc(-c5ccccc5)cc(-c5ccccc5)c4)nc(-c4cc(-c5ccccc5)c(-n5c6ccc(-c7ccccc7)cc6c6cc(-n7c8ccccc8c8ccccc87)ccc65)c(-c5ccccc5)c4)n3)cc2)cc1 ; N#Cc1ccc2c(c1)c1cc(-n3c4ccccc4c4ccccc43)ccc1n2-c1c(-c2ccccc2)cc(-c2nc(-c3ccc(-c4ccccc4)cc3)nc(-c3cc(-c4ccccc4)cc(-c4ccccc4)c3)n2)cc1-c1ccccc1]

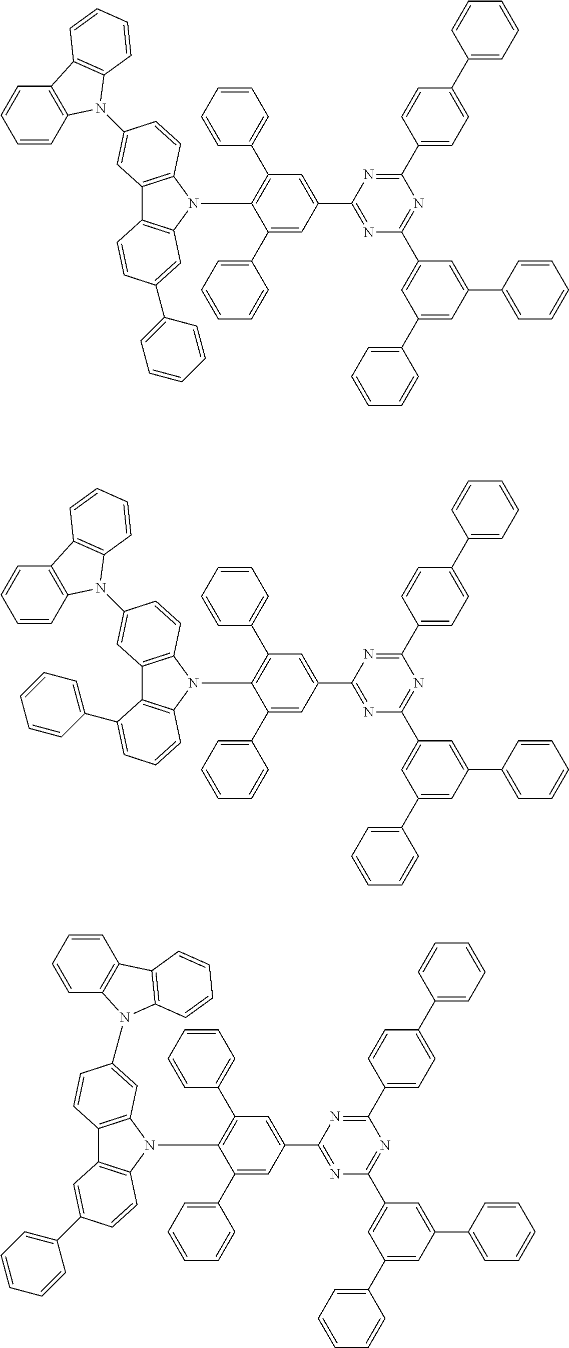 [SMILES: c1ccc(-c2ccc(-c3nc(-c4cc(-c5ccccc5)cc(-c5ccccc5)c4)nc(-c4cc(-c5ccccc5)c(-n5c6ccc(-n7c8ccccc8c8ccccc87)cc6c6ccc(-c7ccccc7)cc65)c(-c5ccccc5)c4)n3)cc2)cc1 ; c1ccc(-c2ccc(-c3nc(-c4cc(-c5ccccc5)cc(-c5ccccc5)c4)nc(-c4cc(-c5ccccc5)c(-n5c6ccc(-n7c8ccccc8c8ccccc87)cc6c6c(-c7ccccc7)cccc65)c(-c5ccccc5)c4)n3)cc2)cc1 ; c1ccc(-c2ccc(-c3nc(-c4cc(-c5ccccc5)cc(-c5ccccc5)c4)nc(-c4cc(-c5ccccc5)c(-n5c6ccc(-c7ccccc7)cc6c6ccc(-n7c8ccccc8c8ccccc87)cc65)c(-c5ccccc5)c4)n3)cc2)cc1]

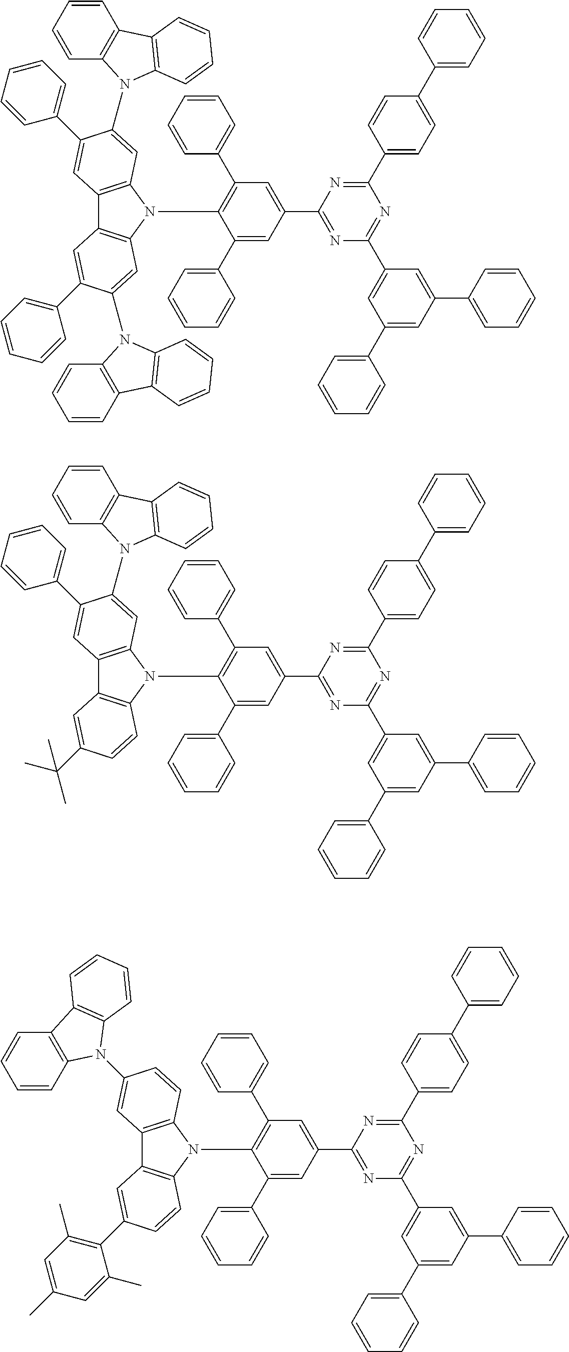

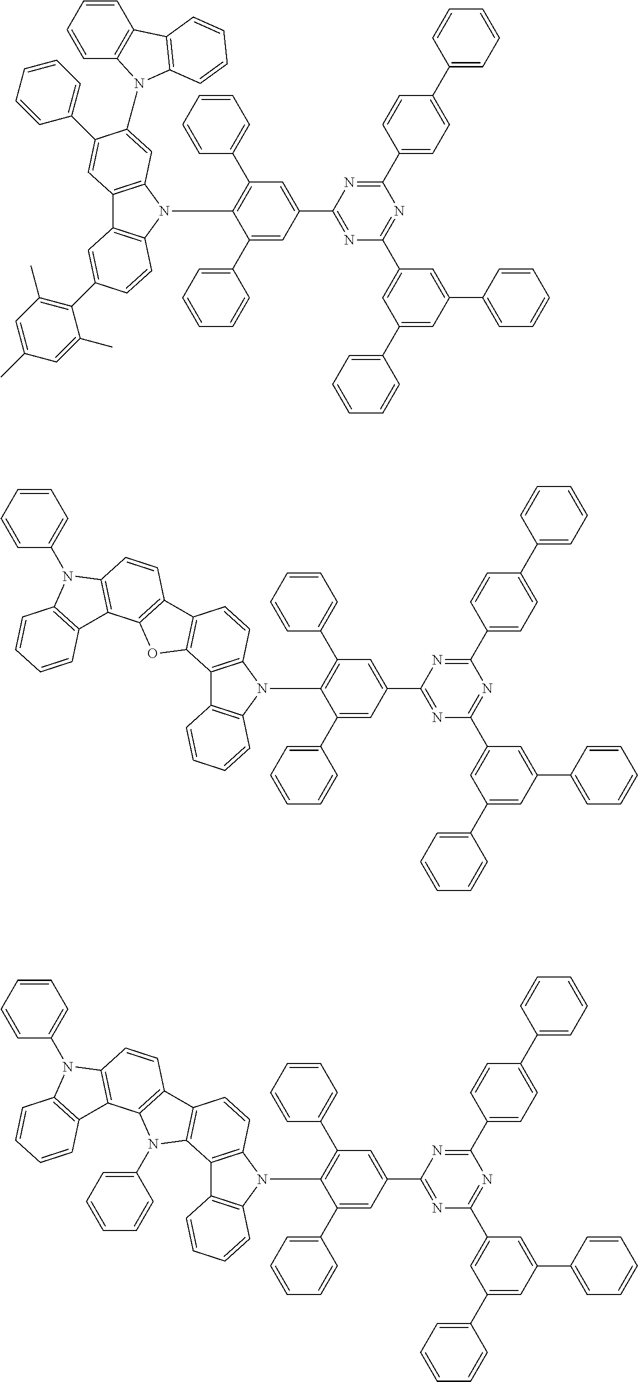 [SMILES: Cc1cc(C)c(-c2ccc3c(c2)c2cc(-c4ccccc4)c(-n4c5ccccc5c5ccccc54)cc2n3-c2c(-c3ccccc3)cc(-c3nc(-c4ccc(-c5ccccc5)cc4)nc(-c4cc(-c5ccccc5)cc(-c5ccccc5)c4)n3)cc2-c2ccccc2)c(C)c1 ; c1ccc(-c2ccc(-c3nc(-c4cc(-c5ccccc5)cc(-c5ccccc5)c4)nc(-c4cc(-c5ccccc5)c(-n5c6ccccc6c6c7oc8c(ccc9c8c8ccccc8n9-c8ccccc8)c7ccc65)c(-c5ccccc5)c4)n3)cc2)cc1 ; c1ccc(-c2ccc(-c3nc(-c4cc(-c5ccccc5)cc(-c5ccccc5)c4)nc(-c4cc(-c5ccccc5)c(-n5c6ccccc6c6c5ccc5c7ccc8c(c9ccccc9n8-c8ccccc8)c7n(-c7ccccc7)c56)c(-c5ccccc5)c4)n3)cc2)cc1]

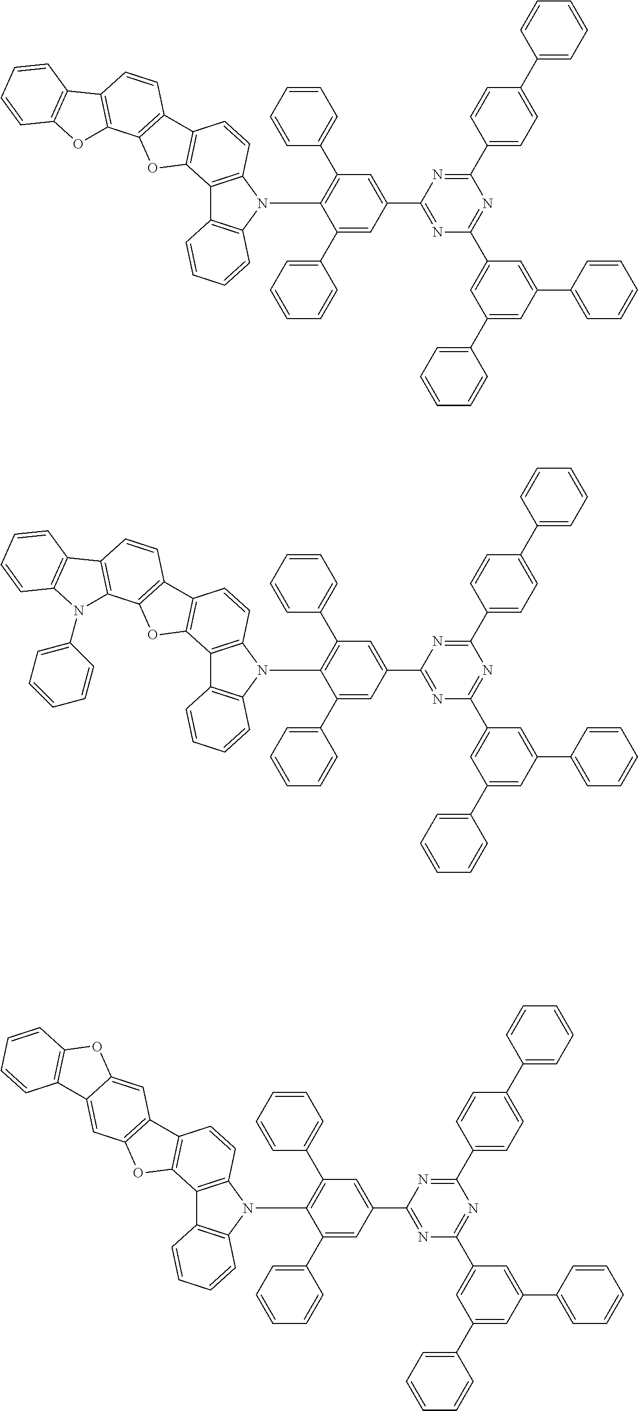 [SMILES: c1ccc(-c2ccc(-c3nc(-c4cc(-c5ccccc5)cc(-c5ccccc5)c4)nc(-c4cc(-c5ccccc5)c(-n5c6ccccc6c6c7oc8c(ccc9c%10ccccc%10oc98)c7ccc65)c(-c5ccccc5)c4)n3)cc2)cc1 ; c1ccc(-c2ccc(-c3nc(-c4cc(-c5ccccc5)cc(-c5ccccc5)c4)nc(-c4cc(-c5ccccc5)c(-n5c6ccccc6c6c7oc8c(ccc9c%10ccccc%10n(-c%10ccccc%10)c98)c7ccc65)c(-c5ccccc5)c4)n3)cc2)cc1 ; c1ccc(-c2ccc(-c3nc(-c4cc(-c5ccccc5)cc(-c5ccccc5)c4)nc(-c4cc(-c5ccccc5)c(-n5c6ccccc6c6c7oc8cc9c(cc8c7ccc65)oc5ccccc59)c(-c5ccccc5)c4)n3)cc2)cc1]

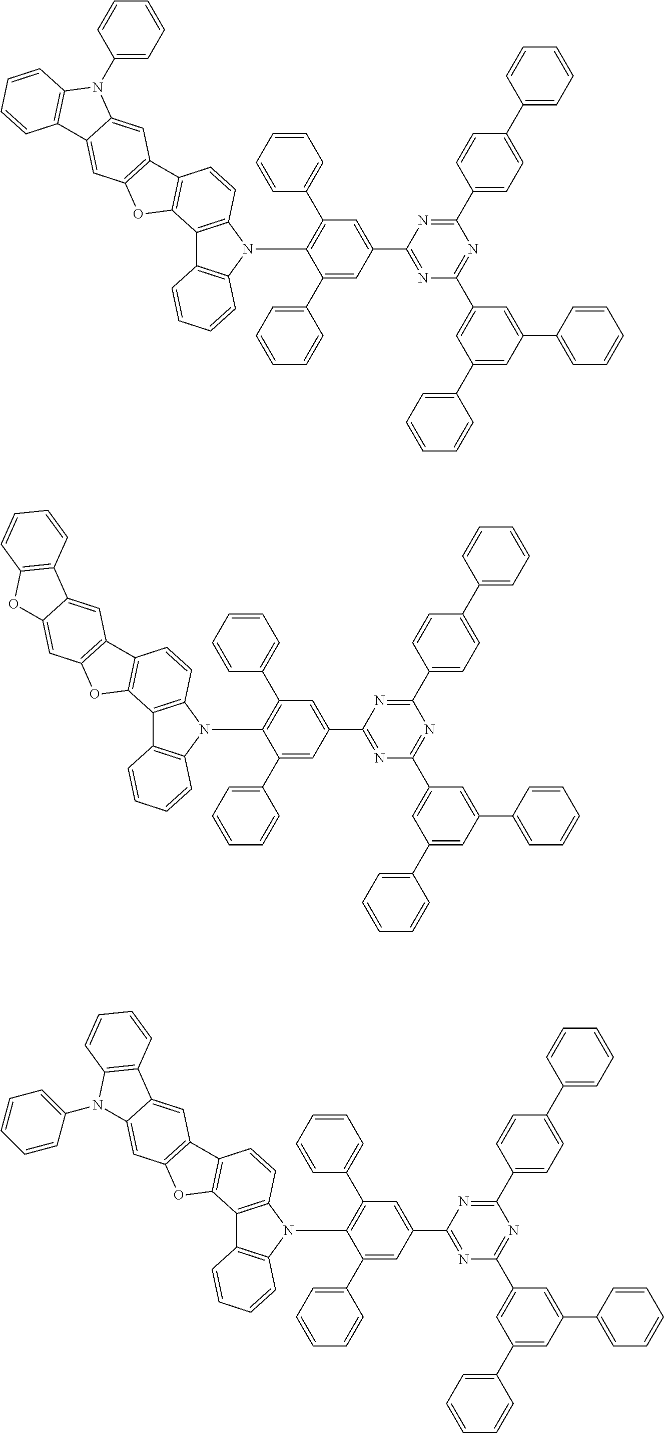 [SMILES: c1ccc(-c2ccc(-c3nc(-c4cc(-c5ccccc5)cc(-c5ccccc5)c4)nc(-c4cc(-c5ccccc5)c(-n5c6ccccc6c6c7oc8cc9c%10ccccc%10n(-c%10ccccc%10)c9cc8c7ccc65)c(-c5ccccc5)c4)n3)cc2)cc1 ; c1ccc(-c2ccc(-c3nc(-c4cc(-c5ccccc5)cc(-c5ccccc5)c4)nc(-c4cc(-c5ccccc5)c(-n5c6ccccc6c6c7oc8cc9oc%10ccccc%10c9cc8c7ccc65)c(-c5ccccc5)c4)n3)cc2)cc1 ; c1ccc(-c2ccc(-c3nc(-c4cc(-c5ccccc5)cc(-c5ccccc5)c4)nc(-c4cc(-c5ccccc5)c(-n5c6ccccc6c6c7oc8cc9c(cc8c7ccc65)c5ccccc5n9-c5ccccc5)c(-c5ccccc5)c4)n3)cc2)cc1]

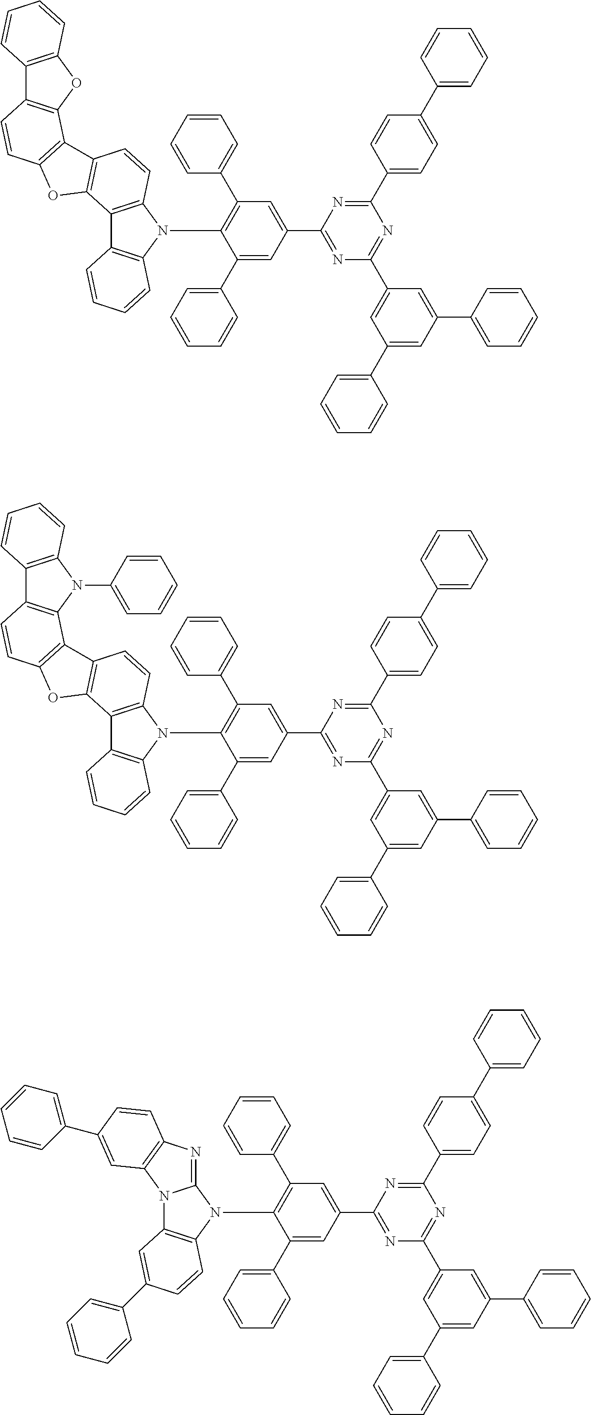 [SMILES: c1ccc(-c2ccc(-c3nc(-c4cc(-c5ccccc5)cc(-c5ccccc5)c4)nc(-c4cc(-c5ccccc5)c(-n5c6ccccc6c6c7oc8ccc9c%10ccccc%10oc9c8c7ccc65)c(-c5ccccc5)c4)n3)cc2)cc1 ; c1ccc(-c2ccc(-c3nc(-c4cc(-c5ccccc5)cc(-c5ccccc5)c4)nc(-c4cc(-c5ccccc5)c(-n5c6ccccc6c6c7oc8ccc9c%10ccccc%10n(-c%10ccccc%10)c9c8c7ccc65)c(-c5ccccc5)c4)n3)cc2)cc1 ; c1ccc(-c2ccc(-c3nc(-c4cc(-c5ccccc5)cc(-c5ccccc5)c4)nc(-c4cc(-c5ccccc5)c(-n5c6ccc(-c7ccccc7)cc6n6c7cc(-c8ccccc8)ccc7nc56)c(-c5ccccc5)c4)n3)cc2)cc1]

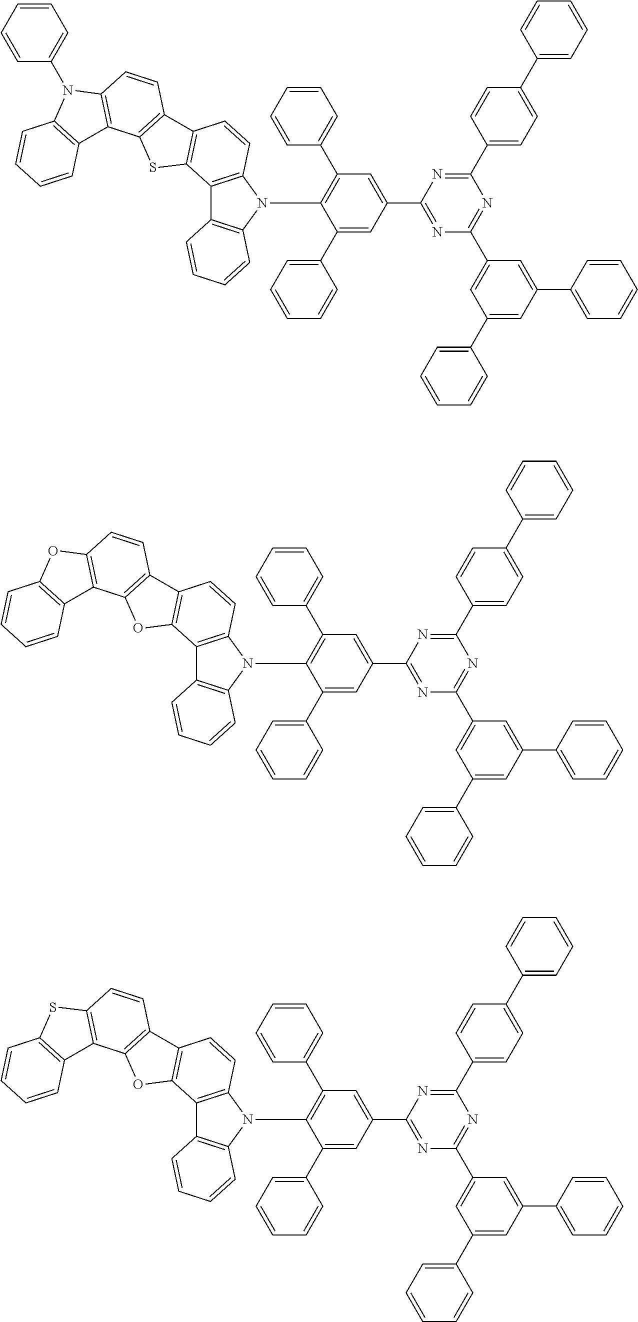 [SMILES: c1ccc(-c2ccc(-c3nc(-c4cc(-c5ccccc5)cc(-c5ccccc5)c4)nc(-c4cc(-c5ccccc5)c(-n5c6ccccc6c6c7sc8c(ccc9c8c8ccccc8n9-c8ccccc8)c7ccc65)c(-c5ccccc5)c4)n3)cc2)cc1 ; c1ccc(-c2ccc(-c3nc(-c4cc(-c5ccccc5)cc(-c5ccccc5)c4)nc(-c4cc(-c5ccccc5)c(-n5c6ccccc6c6c7oc8c(ccc9oc%10ccccc%10c98)c7ccc65)c(-c5ccccc5)c4)n3)cc2)cc1 ; c1ccc(-c2ccc(-c3nc(-c4cc(-c5ccccc5)cc(-c5ccccc5)c4)nc(-c4cc(-c5ccccc5)c(-n5c6ccccc6c6c7oc8c(ccc9sc%10ccccc%10c98)c7ccc65)c(-c5ccccc5)c4)n3)cc2)cc1]

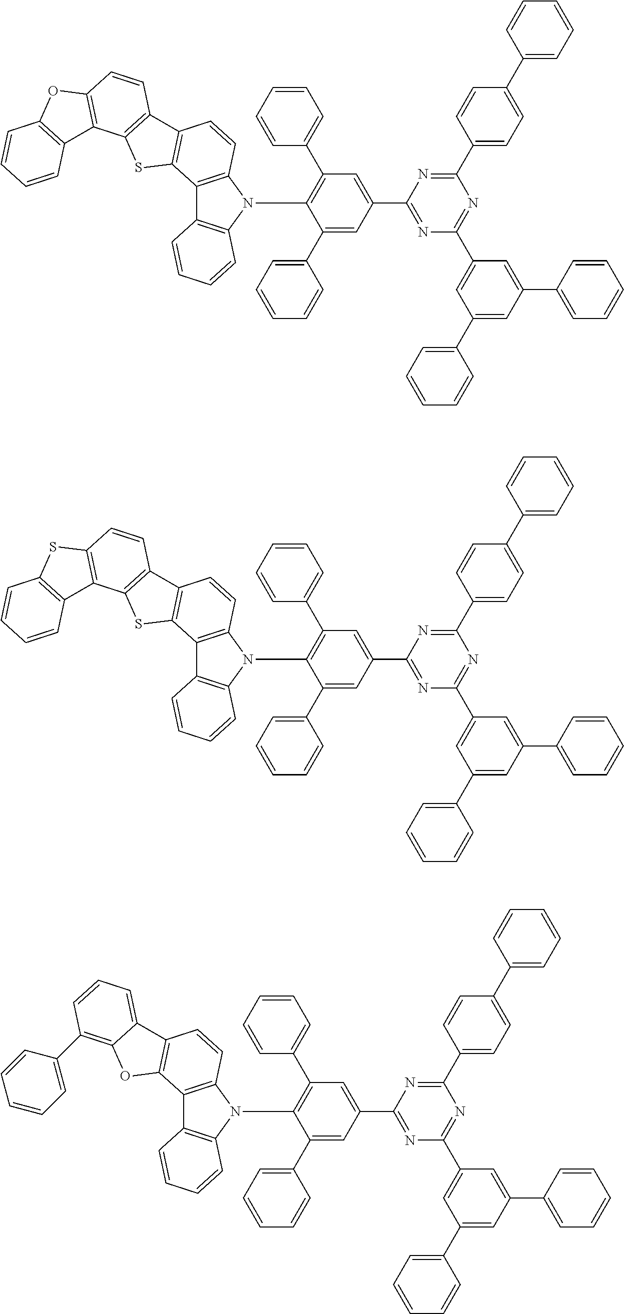 [SMILES: c1ccc(-c2ccc(-c3nc(-c4cc(-c5ccccc5)cc(-c5ccccc5)c4)nc(-c4cc(-c5ccccc5)c(-n5c6ccccc6c6c7sc8c(ccc9oc%10ccccc%10c98)c7ccc65)c(-c5ccccc5)c4)n3)cc2)cc1 ; c1ccc(-c2ccc(-c3nc(-c4cc(-c5ccccc5)cc(-c5ccccc5)c4)nc(-c4cc(-c5ccccc5)c(-n5c6ccccc6c6c7sc8c(ccc9sc%10ccccc%10c98)c7ccc65)c(-c5ccccc5)c4)n3)cc2)cc1 ; c1ccc(-c2ccc(-c3nc(-c4cc(-c5ccccc5)cc(-c5ccccc5)c4)nc(-c4cc(-c5ccccc5)c(-n5c6ccccc6c6c7oc8c(-c9ccccc9)cccc8c7ccc65)c(-c5ccccc5)c4)n3)cc2)cc1]

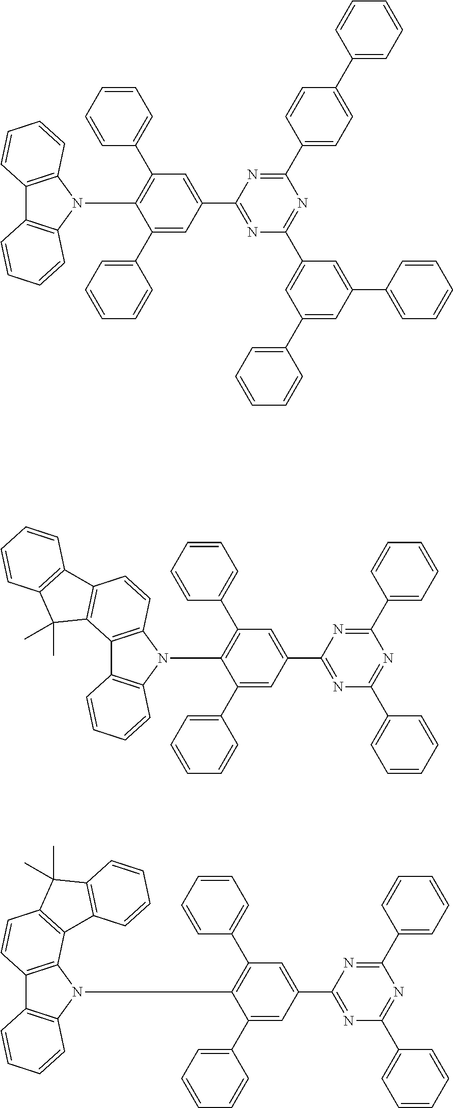 [SMILES: c1ccc(-c2ccc(-c3nc(-c4cc(-c5ccccc5)cc(-c5ccccc5)c4)nc(-c4cc(-c5ccccc5)c(-n5c6ccccc6c6ccccc65)c(-c5ccccc5)c4)n3)cc2)cc1 ; CC1(C)c2ccccc2-c2ccc3c(c21)c1ccccc1n3-c1c(-c2ccccc2)cc(-c2nc(-c3ccccc3)nc(-c3ccccc3)n2)cc1-c1ccccc1 ; CC1(C)c2ccccc2-c2c1ccc1c3ccccc3n(-c3c(-c4ccccc4)cc(-c4nc(-c5ccccc5)nc(-c5ccccc5)n4)cc3-c3ccccc3)c21]

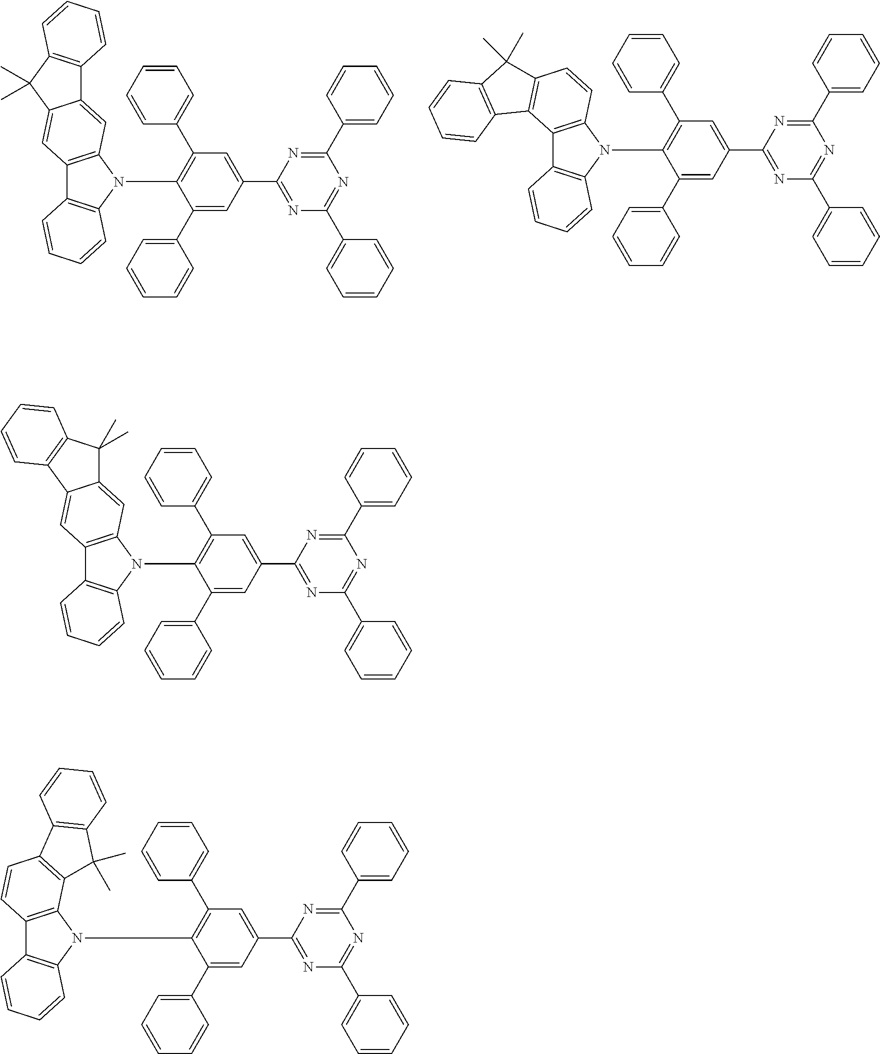

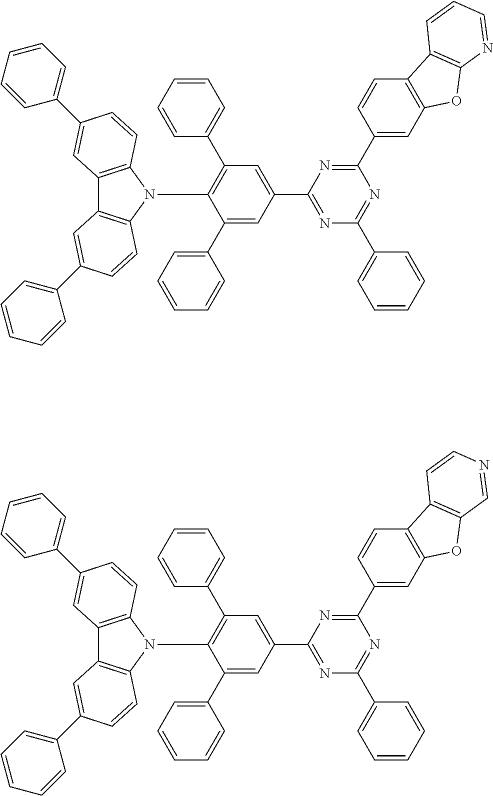 [SMILES: c1ccc(-c2ccc3c(c2)c2cc(-c4ccccc4)ccc2n3-c2c(-c3ccccc3)cc(-c3nc(-c4ccccc4)nc(-c4ccc5c(c4)oc4ncccc45)n3)cc2-c2ccccc2)cc1 ; c1ccc(-c2ccc3c(c2)c2cc(-c4ccccc4)ccc2n3-c2c(-c3ccccc3)cc(-c3nc(-c4ccccc4)nc(-c4ccc5c(c4)oc4cnccc45)n3)cc2-c2ccccc2)cc1]

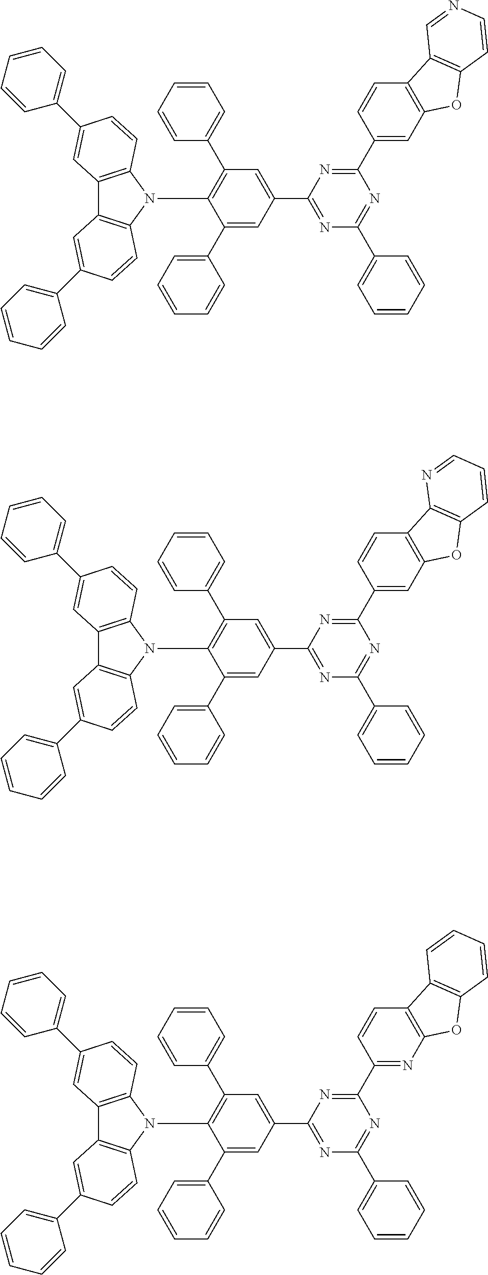 [SMILES: c1ccc(-c2ccc3c(c2)c2cc(-c4ccccc4)ccc2n3-c2c(-c3ccccc3)cc(-c3nc(-c4ccccc4)nc(-c4ccc5c(c4)oc4ccncc45)n3)cc2-c2ccccc2)cc1 ; c1ccc(-c2ccc3c(c2)c2cc(-c4ccccc4)ccc2n3-c2c(-c3ccccc3)cc(-c3nc(-c4ccccc4)nc(-c4ccc5c(c4)oc4cccnc45)n3)cc2-c2ccccc2)cc1 ; c1ccc(-c2ccc3c(c2)c2cc(-c4ccccc4)ccc2n3-c2c(-c3ccccc3)cc(-c3nc(-c4ccccc4)nc(-c4ccc5c(n4)oc4ccccc45)n3)cc2-c2ccccc2)cc1]

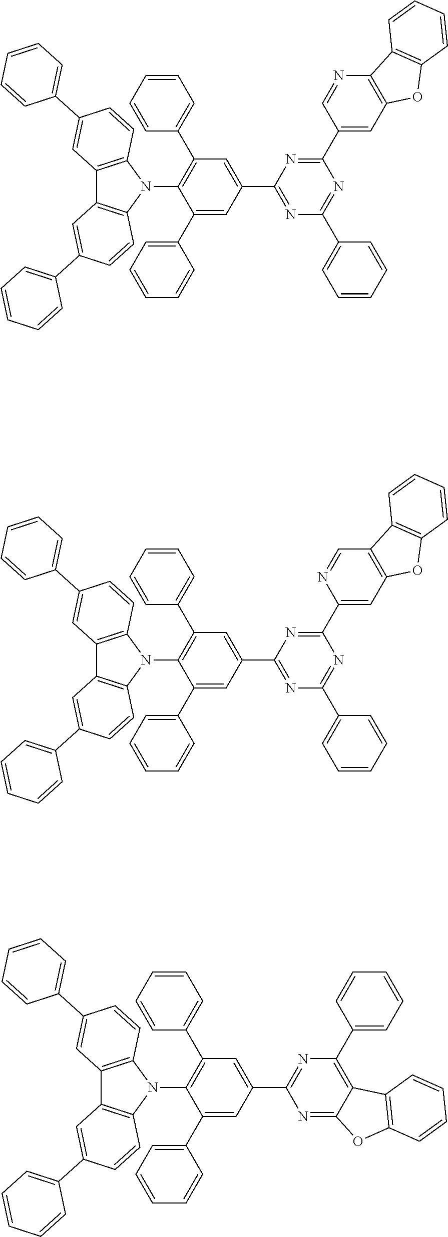 [SMILES: c1ccc(-c2ccc3c(c2)c2cc(-c4ccccc4)ccc2n3-c2c(-c3ccccc3)cc(-c3nc(-c4ccccc4)nc(-c4cnc5c(c4)oc4ccccc45)n3)cc2-c2ccccc2)cc1 ; c1ccc(-c2ccc3c(c2)c2cc(-c4ccccc4)ccc2n3-c2c(-c3ccccc3)cc(-c3nc(-c4ccccc4)nc(-c4cc5oc6ccccc6c5cn4)n3)cc2-c2ccccc2)cc1 ; c1ccc(-c2ccc3c(c2)c2cc(-c4ccccc4)ccc2n3-c2c(-c3ccccc3)cc(-c3nc(-c4ccccc4)c4c(n3)oc3ccccc34)cc2-c2ccccc2)cc1]

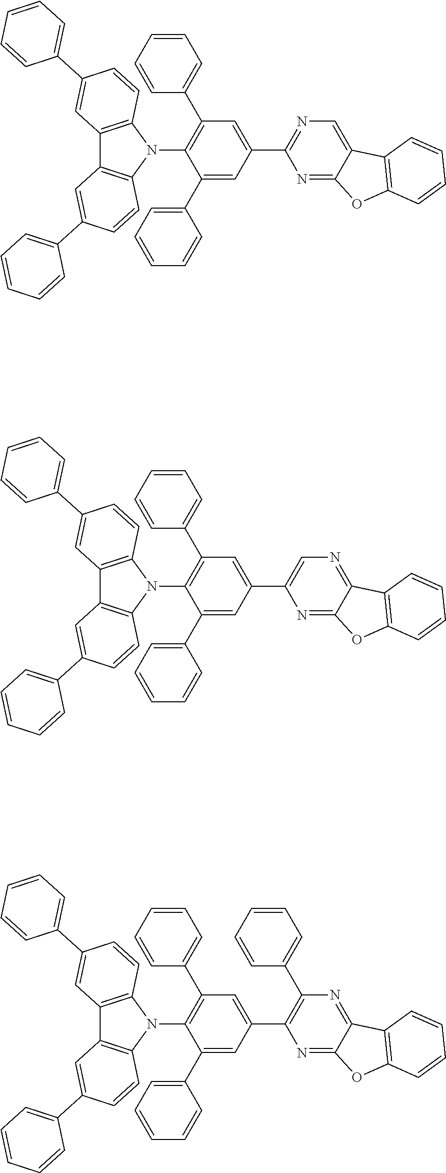 [SMILES: c1ccc(-c2ccc3c(c2)c2cc(-c4ccccc4)ccc2n3-c2c(-c3ccccc3)cc(-c3ncc4c(n3)oc3ccccc34)cc2-c2ccccc2)cc1 ; c1ccc(-c2ccc3c(c2)c2cc(-c4ccccc4)ccc2n3-c2c(-c3ccccc3)cc(-c3cnc4c(n3)oc3ccccc34)cc2-c2ccccc2)cc1 ; c1ccc(-c2ccc3c(c2)c2cc(-c4ccccc4)ccc2n3-c2c(-c3ccccc3)cc(-c3nc4oc5ccccc5c4nc3-c3ccccc3)cc2-c2ccccc2)cc1]

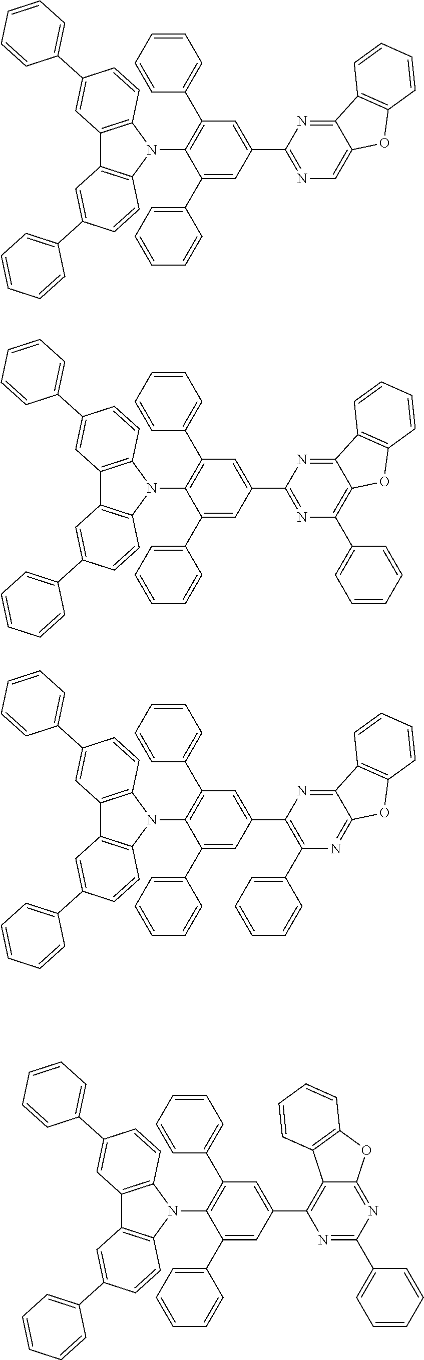

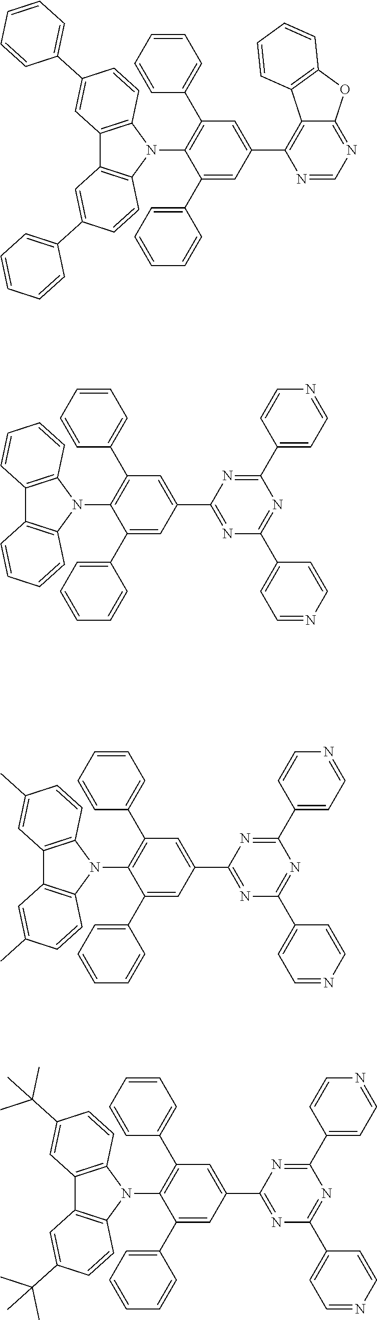 [SMILES: c1ccc(-c2ccc3c(c2)c2cc(-c4ccccc4)ccc2n3-c2c(-c3ccccc3)cc(-c3ncnc4oc5ccccc5c34)cc2-c2ccccc2)cc1 ; c1ccc(-c2cc(-c3nc(-c4ccncc4)nc(-c4ccncc4)n3)cc(-c3ccccc3)c2-n2c3ccccc3c3ccccc32)cc1 ; Cc1ccc2c(c1)c1cc(C)ccc1n2-c1c(-c2ccccc2)cc(-c2nc(-c3ccncc3)nc(-c3ccncc3)n2)cc1-c1ccccc1 ; CC(C)(C)c1ccc2c(c1)c1cc(C(C)(C)C)ccc1n2-c1c(-c2ccccc2)cc(-c2nc(-c3ccncc3)nc(-c3ccncc3)n2)cc1-c1ccccc1]

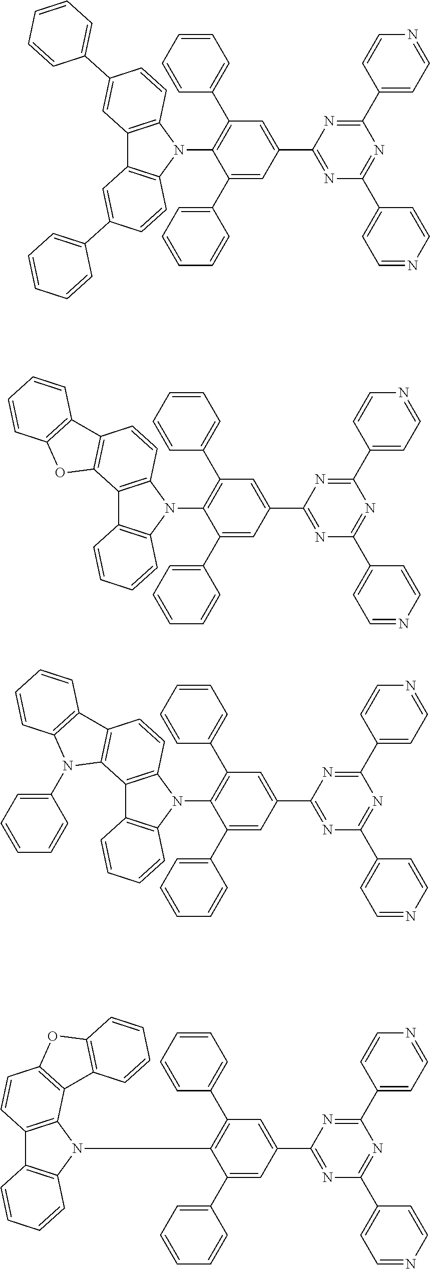 [SMILES: c1ccc(-c2ccc3c(c2)c2cc(-c4ccccc4)ccc2n3-c2c(-c3ccccc3)cc(-c3nc(-c4ccncc4)nc(-c4ccncc4)n3)cc2-c2ccccc2)cc1 ; c1ccc(-c2cc(-c3nc(-c4ccncc4)nc(-c4ccncc4)n3)cc(-c3ccccc3)c2-n2c3ccccc3c3c4oc5ccccc5c4ccc32)cc1 ; c1ccc(-c2cc(-c3nc(-c4ccncc4)nc(-c4ccncc4)n3)cc(-c3ccccc3)c2-n2c3ccccc3c3c2ccc2c4ccccc4n(-c4ccccc4)c23)cc1 ; c1ccc(-c2cc(-c3nc(-c4ccncc4)nc(-c4ccncc4)n3)cc(-c3ccccc3)c2-n2c3ccccc3c3ccc4oc5ccccc5c4c32)cc1]

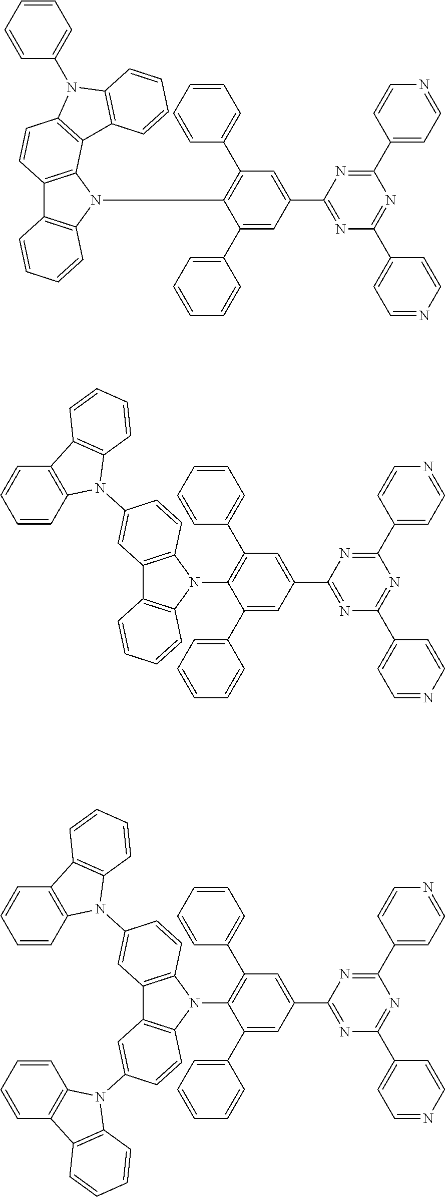 [SMILES: c1ccc(-c2cc(-c3nc(-c4ccncc4)nc(-c4ccncc4)n3)cc(-c3ccccc3)c2-n2c3ccccc3c3ccc4c(c5ccccc5n4-c4ccccc4)c32)cc1 ; c1ccc(-c2cc(-c3nc(-c4ccncc4)nc(-c4ccncc4)n3)cc(-c3ccccc3)c2-n2c3ccccc3c3cc(-n4c5ccccc5c5ccccc54)ccc32)cc1 ; c1ccc(-c2cc(-c3nc(-c4ccncc4)nc(-c4ccncc4)n3)cc(-c3ccccc3)c2-n2c3ccc(-n4c5ccccc5c5ccccc54)cc3c3cc(-n4c5ccccc5c5ccccc54)ccc32)cc1]

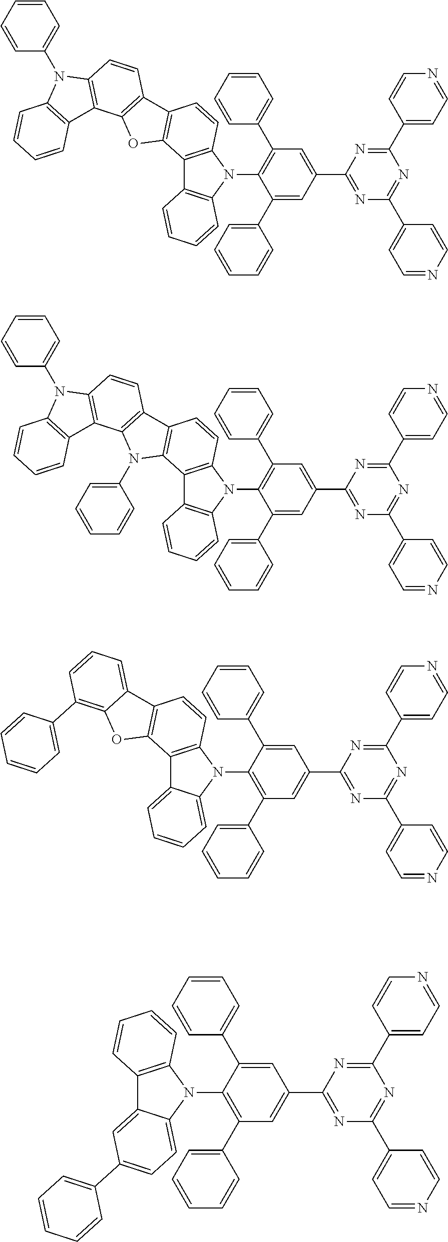 [SMILES: c1ccc(-c2cc(-c3nc(-c4ccncc4)nc(-c4ccncc4)n3)cc(-c3ccccc3)c2-n2c3ccccc3c3c4oc5c(ccc6c5c5ccccc5n6-c5ccccc5)c4ccc32)cc1 ; c1ccc(-c2cc(-c3nc(-c4ccncc4)nc(-c4ccncc4)n3)cc(-c3ccccc3)c2-n2c3ccccc3c3c2ccc2c4ccc5c(c6ccccc6n5-c5ccccc5)c4n(-c4ccccc4)c23)cc1 ; c1ccc(-c2cc(-c3nc(-c4ccncc4)nc(-c4ccncc4)n3)cc(-c3ccccc3)c2-n2c3ccccc3c3c4oc5c(-c6ccccc6)cccc5c4ccc32)cc1 ; c1ccc(-c2ccc3c(c2)c2ccccc2n3-c2c(-c3ccccc3)cc(-c3nc(-c4ccncc4)nc(-c4ccncc4)n3)cc2-c2ccccc2)cc1]

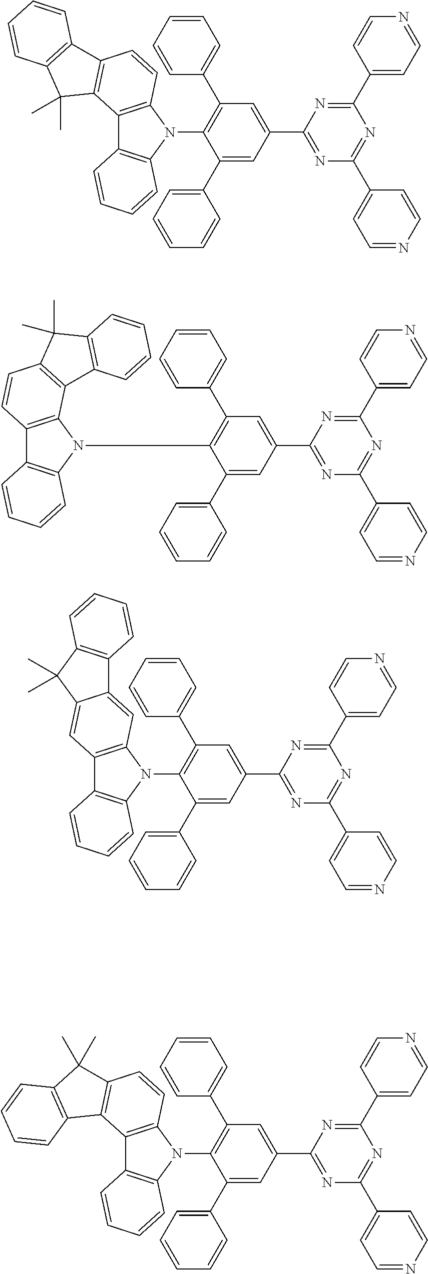 [SMILES: CC1(C)c2ccccc2-c2ccc3c(c21)c1ccccc1n3-c1c(-c2ccccc2)cc(-c2nc(-c3ccncc3)nc(-c3ccncc3)n2)cc1-c1ccccc1 ; CC1(C)c2ccccc2-c2c1ccc1c3ccccc3n(-c3c(-c4ccccc4)cc(-c4nc(-c5ccncc5)nc(-c5ccncc5)n4)cc3-c3ccccc3)c21 ; CC1(C)c2ccccc2-c2cc3c(cc21)c1ccccc1n3-c1c(-c2ccccc2)cc(-c2nc(-c3ccncc3)nc(-c3ccncc3)n2)cc1-c1ccccc1 ; CC1(C)c2ccccc2-c2c1ccc1c2c2ccccc2n1-c1c(-c2ccccc2)cc(-c2nc(-c3ccncc3)nc(-c3ccncc3)n2)cc1-c1ccccc1]

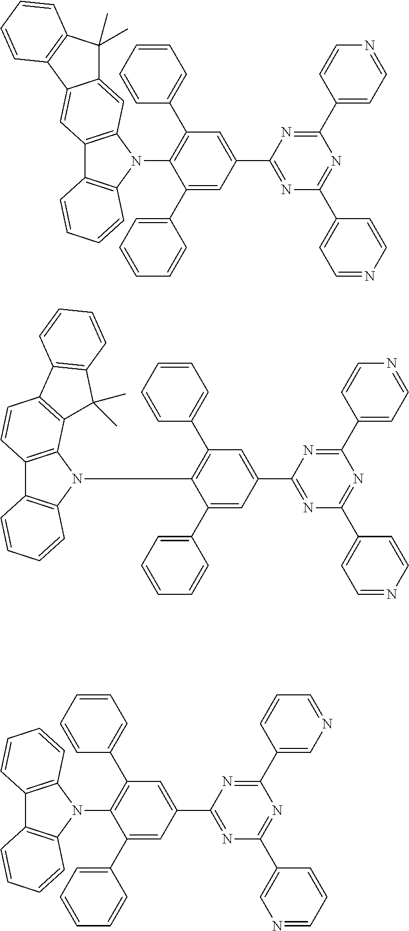 [SMILES: CC1(C)c2ccccc2-c2cc3c4ccccc4n(-c4c(-c5ccccc5)cc(-c5nc(-c6ccncc6)nc(-c6ccncc6)n5)cc4-c4ccccc4)c3cc21 ; CC1(C)c2ccccc2-c2ccc3c4ccccc4n(-c4c(-c5ccccc5)cc(-c5nc(-c6ccncc6)nc(-c6ccncc6)n5)cc4-c4ccccc4)c3c21 ; c1ccc(-c2cc(-c3nc(-c4cccnc4)nc(-c4cccnc4)n3)cc(-c3ccccc3)c2-n2c3ccccc3c3ccccc32)cc1]

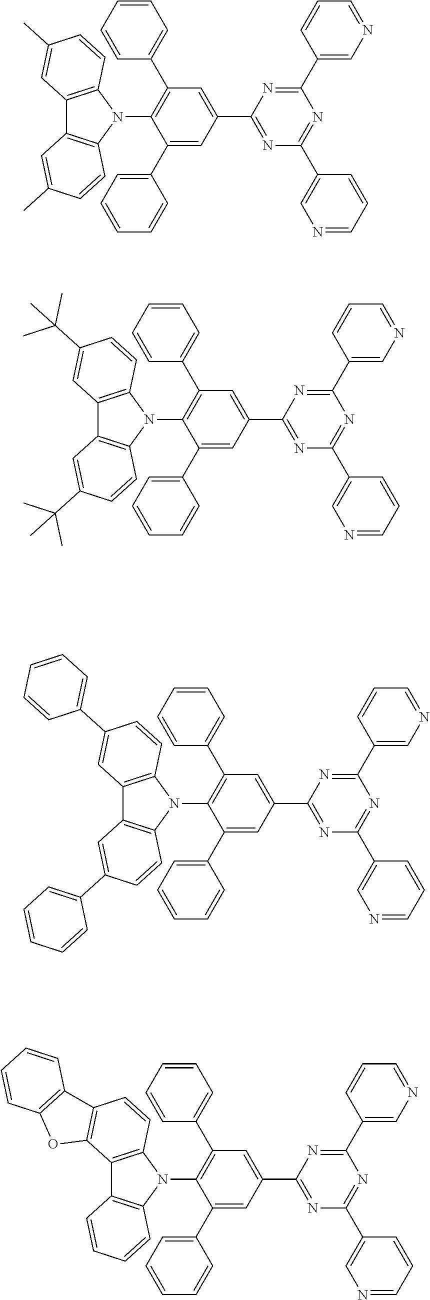 [SMILES: Cc1ccc2c(c1)c1cc(C)ccc1n2-c1c(-c2ccccc2)cc(-c2nc(-c3cccnc3)nc(-c3cccnc3)n2)cc1-c1ccccc1 ; CC(C)(C)c1ccc2c(c1)c1cc(C(C)(C)C)ccc1n2-c1c(-c2ccccc2)cc(-c2nc(-c3cccnc3)nc(-c3cccnc3)n2)cc1-c1ccccc1 ; c1ccc(-c2ccc3c(c2)c2cc(-c4ccccc4)ccc2n3-c2c(-c3ccccc3)cc(-c3nc(-c4cccnc4)nc(-c4cccnc4)n3)cc2-c2ccccc2)cc1 ; c1ccc(-c2cc(-c3nc(-c4cccnc4)nc(-c4cccnc4)n3)cc(-c3ccccc3)c2-n2c3ccccc3c3c4oc5ccccc5c4ccc32)cc1]

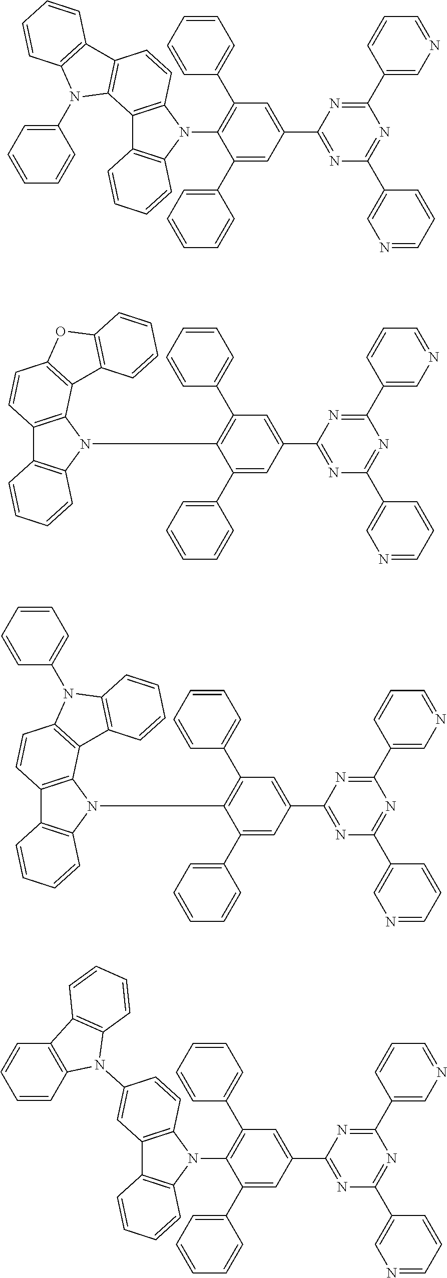 [SMILES: c1ccc(-c2cc(-c3nc(-c4cccnc4)nc(-c4cccnc4)n3)cc(-c3ccccc3)c2-n2c3ccccc3c3c2ccc2c4ccccc4n(-c4ccccc4)c23)cc1 ; c1ccc(-c2cc(-c3nc(-c4cccnc4)nc(-c4cccnc4)n3)cc(-c3ccccc3)c2-n2c3ccccc3c3ccc4oc5ccccc5c4c32)cc1 ; c1ccc(-c2cc(-c3nc(-c4cccnc4)nc(-c4cccnc4)n3)cc(-c3ccccc3)c2-n2c3ccccc3c3ccc4c(c5ccccc5n4-c4ccccc4)c32)cc1 ; c1ccc(-c2cc(-c3nc(-c4cccnc4)nc(-c4cccnc4)n3)cc(-c3ccccc3)c2-n2c3ccccc3c3cc(-n4c5ccccc5c5ccccc54)ccc32)cc1]

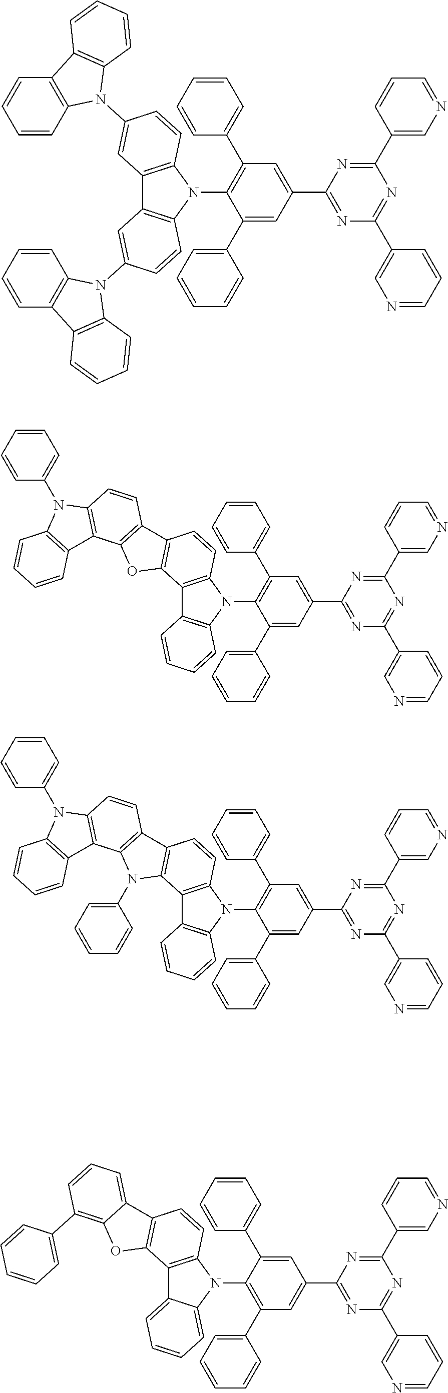 [SMILES: c1ccc(-c2cc(-c3nc(-c4cccnc4)nc(-c4cccnc4)n3)cc(-c3ccccc3)c2-n2c3ccc(-n4c5ccccc5c5ccccc54)cc3c3cc(-n4c5ccccc5c5ccccc54)ccc32)cc1 ; c1ccc(-c2cc(-c3nc(-c4cccnc4)nc(-c4cccnc4)n3)cc(-c3ccccc3)c2-n2c3ccccc3c3c4oc5c(ccc6c5c5ccccc5n6-c5ccccc5)c4ccc32)cc1 ; c1ccc(-c2cc(-c3nc(-c4cccnc4)nc(-c4cccnc4)n3)cc(-c3ccccc3)c2-n2c3ccccc3c3c2ccc2c4ccc5c(c6ccccc6n5-c5ccccc5)c4n(-c4ccccc4)c23)cc1 ; c1ccc(-c2cc(-c3nc(-c4cccnc4)nc(-c4cccnc4)n3)cc(-c3ccccc3)c2-n2c3ccccc3c3c4oc5c(-c6ccccc6)cccc5c4ccc32)cc1]

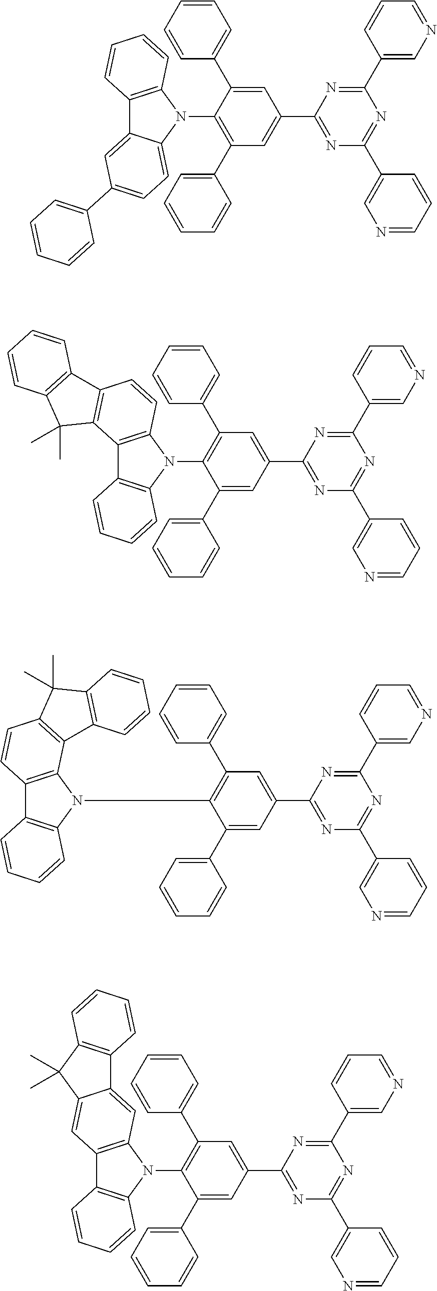 [SMILES: c1ccc(-c2ccc3c(c2)c2ccccc2n3-c2c(-c3ccccc3)cc(-c3nc(-c4cccnc4)nc(-c4cccnc4)n3)cc2-c2ccccc2)cc1 ; CC1(C)c2ccccc2-c2ccc3c(c21)c1ccccc1n3-c1c(-c2ccccc2)cc(-c2nc(-c3cccnc3)nc(-c3cccnc3)n2)cc1-c1ccccc1 ; CC1(C)c2ccccc2-c2c1ccc1c3ccccc3n(-c3c(-c4ccccc4)cc(-c4nc(-c5cccnc5)nc(-c5cccnc5)n4)cc3-c3ccccc3)c21 ; CC1(C)c2ccccc2-c2cc3c(cc21)c1ccccc1n3-c1c(-c2ccccc2)cc(-c2nc(-c3cccnc3)nc(-c3cccnc3)n2)cc1-c1ccccc1]

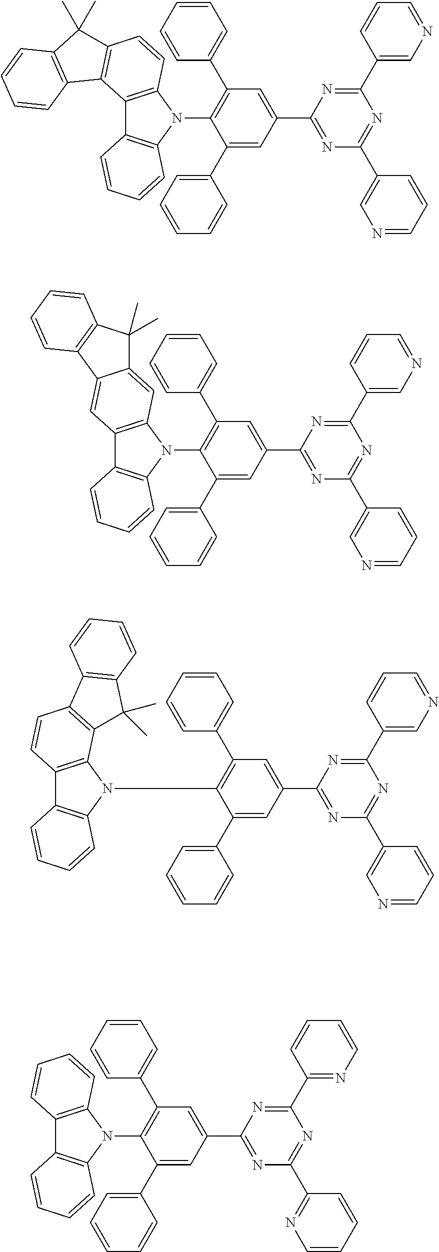 [SMILES: CC1(C)c2ccccc2-c2c1ccc1c2c2ccccc2n1-c1c(-c2ccccc2)cc(-c2nc(-c3cccnc3)nc(-c3cccnc3)n2)cc1-c1ccccc1 ; CC1(C)c2ccccc2-c2cc3c4ccccc4n(-c4c(-c5ccccc5)cc(-c5nc(-c6cccnc6)nc(-c6cccnc6)n5)cc4-c4ccccc4)c3cc21 ; CC1(C)c2ccccc2-c2ccc3c4ccccc4n(-c4c(-c5ccccc5)cc(-c5nc(-c6cccnc6)nc(-c6cccnc6)n5)cc4-c4ccccc4)c3c21 ; c1ccc(-c2cc(-c3nc(-c4ccccn4)nc(-c4ccccn4)n3)cc(-c3ccccc3)c2-n2c3ccccc3c3ccccc32)cc1]

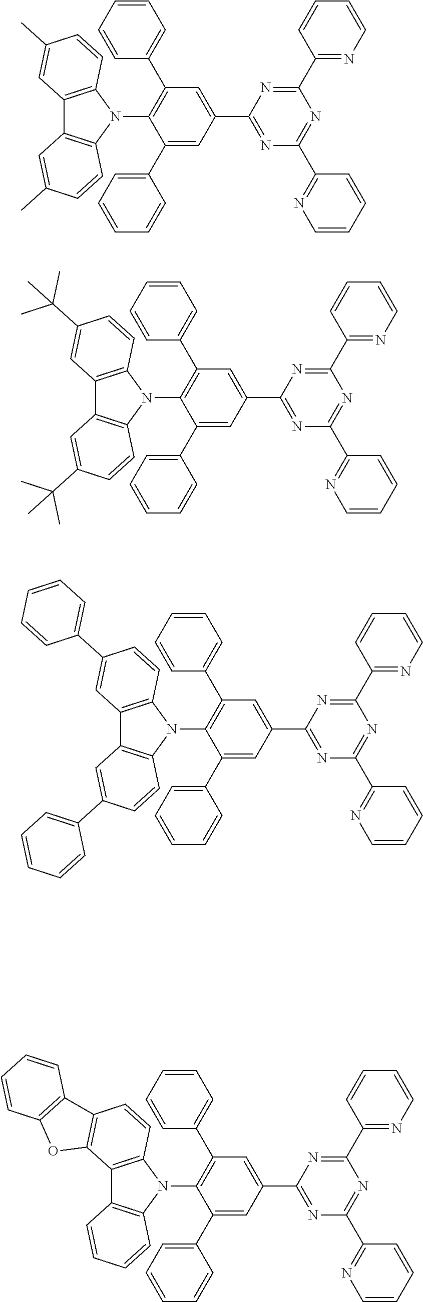 [SMILES: Cc1ccc2c(c1)c1cc(C)ccc1n2-c1c(-c2ccccc2)cc(-c2nc(-c3ccccn3)nc(-c3ccccn3)n2)cc1-c1ccccc1 ; CC(C)(C)c1ccc2c(c1)c1cc(C(C)(C)C)ccc1n2-c1c(-c2ccccc2)cc(-c2nc(-c3ccccn3)nc(-c3ccccn3)n2)cc1-c1ccccc1 ; c1ccc(-c2ccc3c(c2)c2cc(-c4ccccc4)ccc2n3-c2c(-c3ccccc3)cc(-c3nc(-c4ccccn4)nc(-c4ccccn4)n3)cc2-c2ccccc2)cc1 ; c1ccc(-c2cc(-c3nc(-c4ccccn4)nc(-c4ccccn4)n3)cc(-c3ccccc3)c2-n2c3ccccc3c3c4oc5ccccc5c4ccc32)cc1]

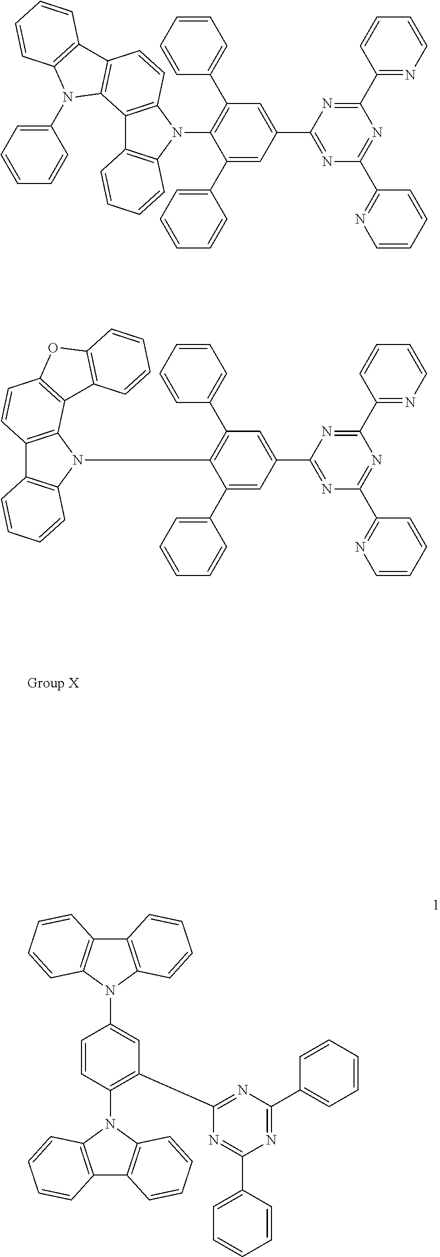 [SMILES: c1ccc(-c2cc(-c3nc(-c4ccccn4)nc(-c4ccccn4)n3)cc(-c3ccccc3)c2-n2c3ccccc3c3c2ccc2c4ccccc4n(-c4ccccc4)c23)cc1 ; c1ccc(-c2cc(-c3nc(-c4ccccn4)nc(-c4ccccn4)n3)cc(-c3ccccc3)c2-n2c3ccccc3c3ccc4oc5ccccc5c4c32)cc1 ; c1ccc(-c2nc(-c3ccccc3)nc(-c3cc(-n4c5ccccc5c5ccccc54)ccc3-n3c4ccccc4c4ccccc43)n2)cc1]

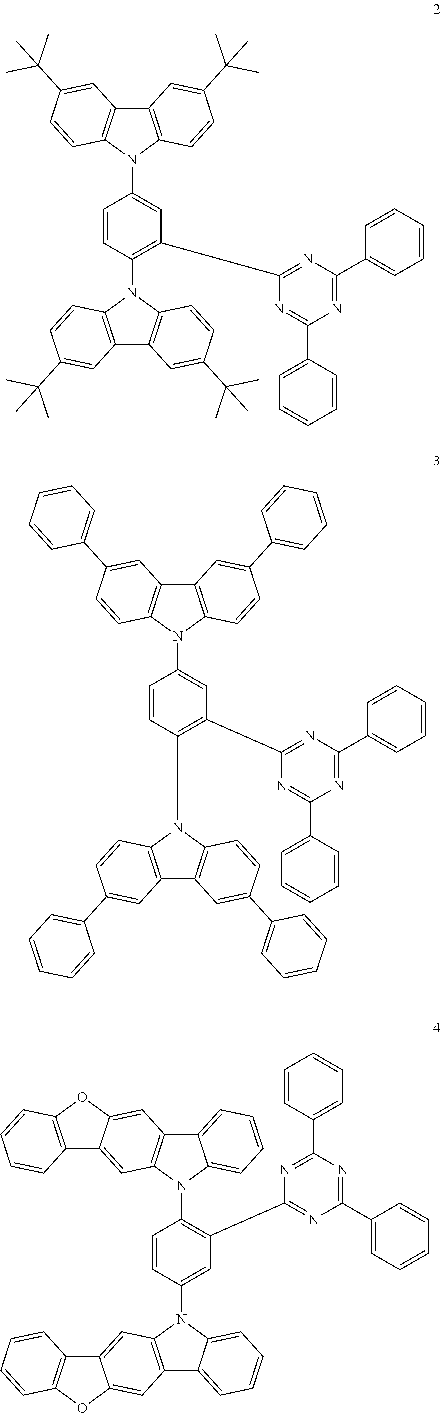 [SMILES: CC(C)(C)c1ccc2c(c1)c1cc(C(C)(C)C)ccc1n2-c1ccc(-n2c3ccc(C(C)(C)C)cc3c3cc(C(C)(C)C)ccc32)c(-c2nc(-c3ccccc3)nc(-c3ccccc3)n2)c1 ; c1ccc(-c2ccc3c(c2)c2cc(-c4ccccc4)ccc2n3-c2ccc(-n3c4ccc(-c5ccccc5)cc4c4cc(-c5ccccc5)ccc43)c(-c3nc(-c4ccccc4)nc(-c4ccccc4)n3)c2)cc1 ; c1ccc(-c2nc(-c3ccccc3)nc(-c3cc(-n4c5ccccc5c5cc6oc7ccccc7c6cc54)ccc3-n3c4ccccc4c4cc5oc6ccccc6c5cc43)n2)cc1]

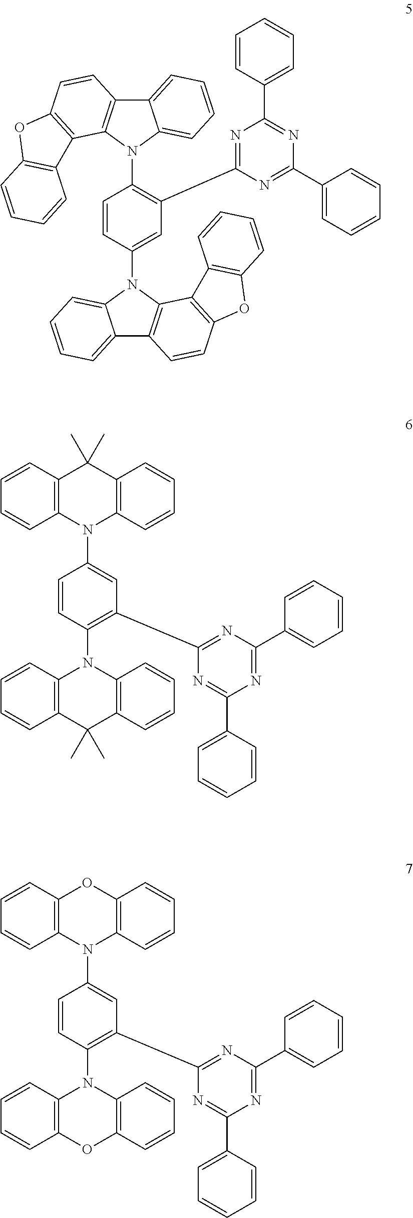 [SMILES: c1ccc(-c2nc(-c3ccccc3)nc(-c3cc(-n4c5ccccc5c5ccc6oc7ccccc7c6c54)ccc3-n3c4ccccc4c4ccc5oc6ccccc6c5c43)n2)cc1 ; CC1(C)c2ccccc2N(c2ccc(N3c4ccccc4C(C)(C)c4ccccc43)c(-c3nc(-c4ccccc4)nc(-c4ccccc4)n3)c2)c2ccccc21 ; c1ccc(-c2nc(-c3ccccc3)nc(-c3cc(N4c5ccccc5Oc5ccccc54)ccc3N3c4ccccc4Oc4ccccc43)n2)cc1]

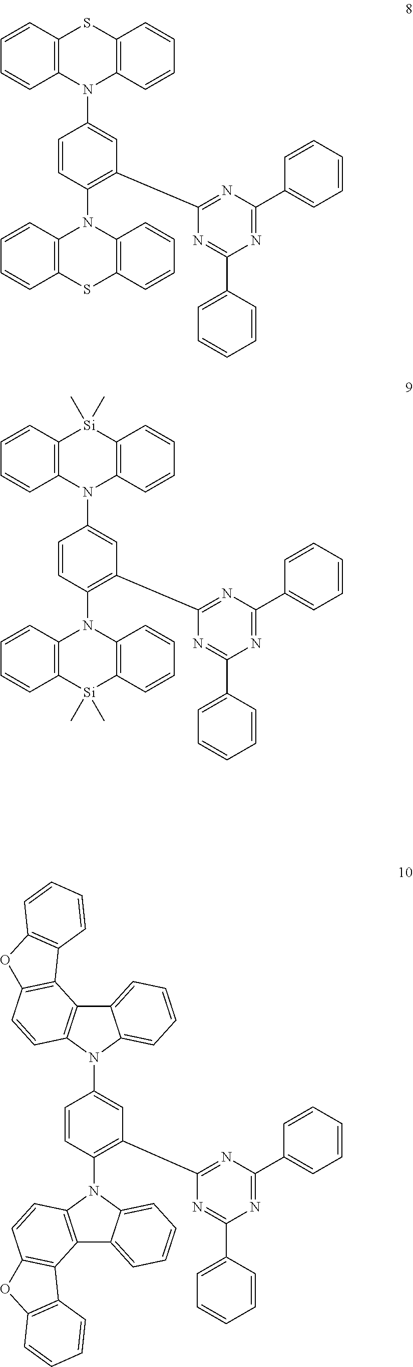 [SMILES: c1ccc(-c2nc(-c3ccccc3)nc(-c3cc(N4c5ccccc5Sc5ccccc54)ccc3N3c4ccccc4Sc4ccccc43)n2)cc1 ; C[Si]1(C)c2ccccc2N(c2ccc(N3c4ccccc4[Si](C)(C)c4ccccc43)c(-c3nc(-c4ccccc4)nc(-c4ccccc4)n3)c2)c2ccccc21 ; c1ccc(-c2nc(-c3ccccc3)nc(-c3cc(-n4c5ccccc5c5c6c(ccc54)oc4ccccc46)ccc3-n3c4ccccc4c4c5c(ccc43)oc3ccccc35)n2)cc1]

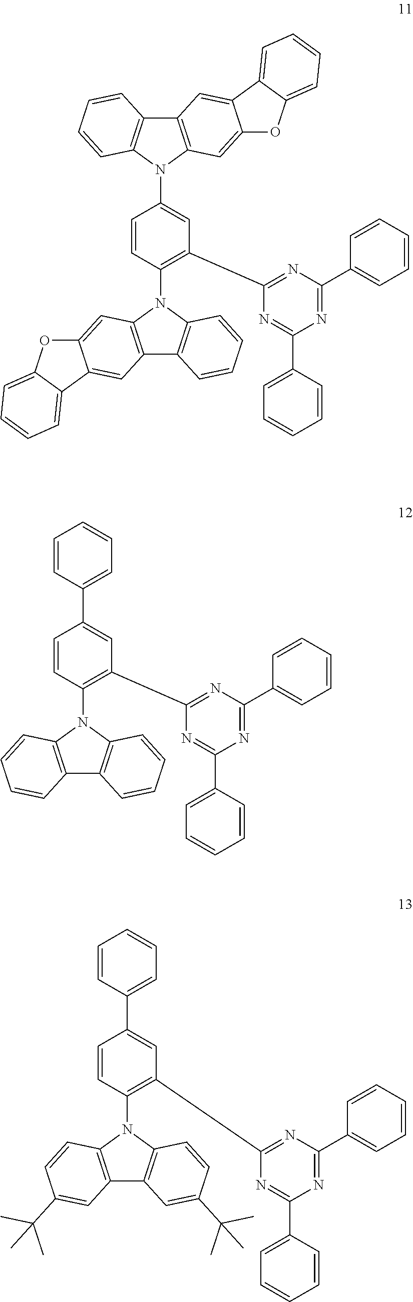 [SMILES: c1ccc(-c2nc(-c3ccccc3)nc(-c3cc(-n4c5ccccc5c5cc6c(cc54)oc4ccccc46)ccc3-n3c4ccccc4c4cc5c(cc43)oc3ccccc35)n2)cc1 ; c1ccc(-c2ccc(-n3c4ccccc4c4ccccc43)c(-c3nc(-c4ccccc4)nc(-c4ccccc4)n3)c2)cc1 ; CC(C)(C)c1ccc2c(c1)c1cc(C(C)(C)C)ccc1n2-c1ccc(-c2ccccc2)cc1-c1nc(-c2ccccc2)nc(-c2ccccc2)n1]

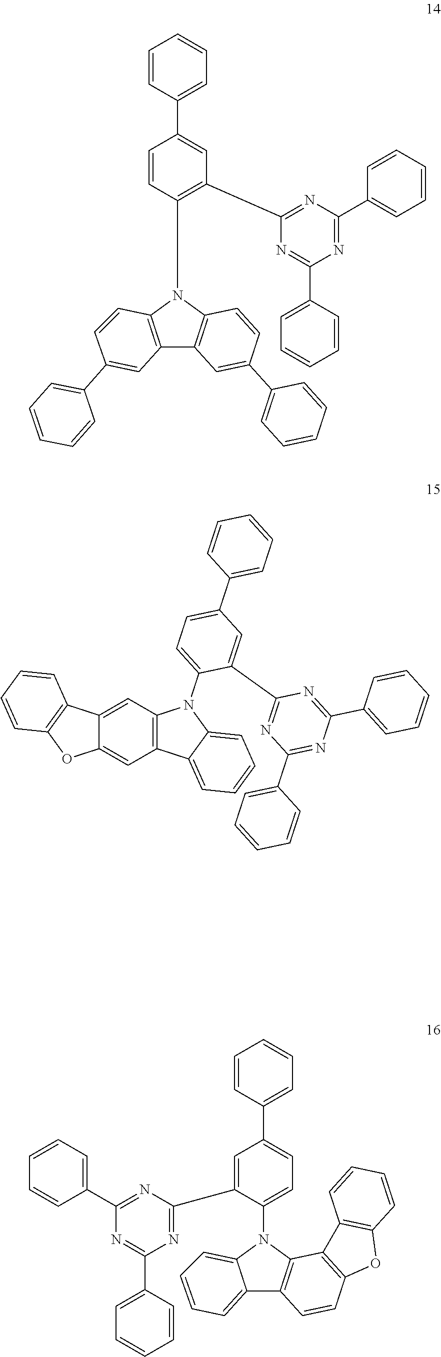 [SMILES: c1ccc(-c2ccc(-n3c4ccc(-c5ccccc5)cc4c4cc(-c5ccccc5)ccc43)c(-c3nc(-c4ccccc4)nc(-c4ccccc4)n3)c2)cc1 ; c1ccc(-c2ccc(-n3c4ccccc4c4cc5oc6ccccc6c5cc43)c(-c3nc(-c4ccccc4)nc(-c4ccccc4)n3)c2)cc1 ; c1ccc(-c2ccc(-n3c4ccccc4c4ccc5oc6ccccc6c5c43)c(-c3nc(-c4ccccc4)nc(-c4ccccc4)n3)c2)cc1]

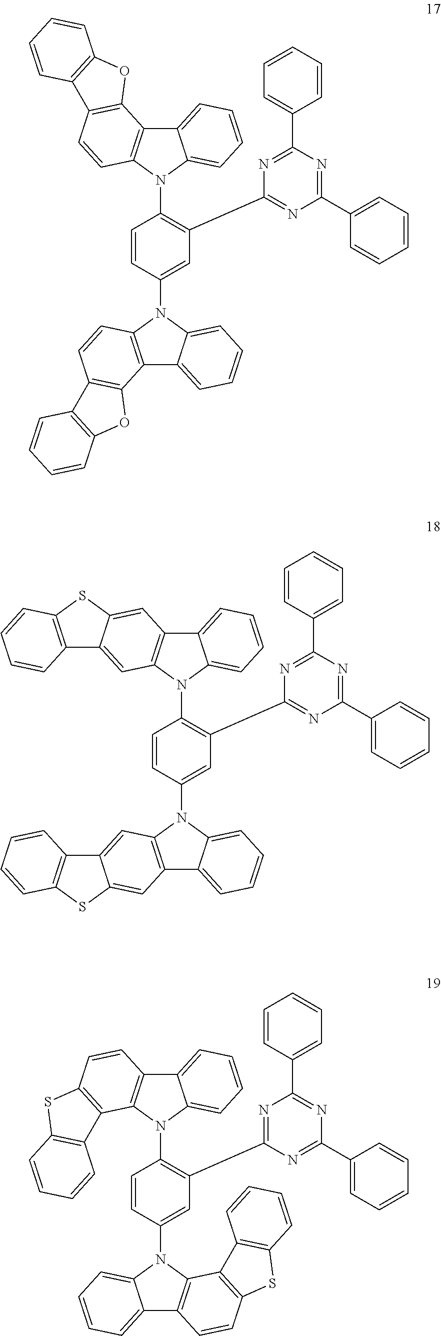 [SMILES: c1ccc(-c2nc(-c3ccccc3)nc(-c3cc(-n4c5ccccc5c5c6oc7ccccc7c6ccc54)ccc3-n3c4ccccc4c4c5oc6ccccc6c5ccc43)n2)cc1 ; c1ccc(-c2nc(-c3ccccc3)nc(-c3cc(-n4c5ccccc5c5cc6sc7ccccc7c6cc54)ccc3-n3c4ccccc4c4cc5sc6ccccc6c5cc43)n2)cc1 ; c1ccc(-c2nc(-c3ccccc3)nc(-c3cc(-n4c5ccccc5c5ccc6sc7ccccc7c6c54)ccc3-n3c4ccccc4c4ccc5sc6ccccc6c5c43)n2)cc1]

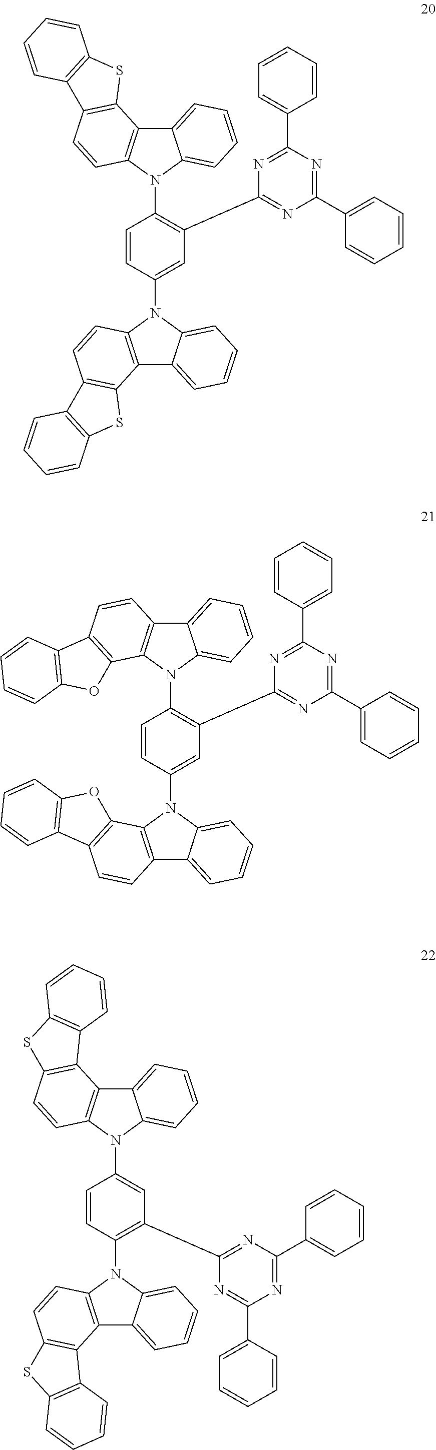 [SMILES: c1ccc(-c2nc(-c3ccccc3)nc(-c3cc(-n4c5ccccc5c5c6sc7ccccc7c6ccc54)ccc3-n3c4ccccc4c4c5sc6ccccc6c5ccc43)n2)cc1 ; c1ccc(-c2nc(-c3ccccc3)nc(-c3cc(-n4c5ccccc5c5ccc6c7ccccc7oc6c54)ccc3-n3c4ccccc4c4ccc5c6ccccc6oc5c43)n2)cc1 ; c1ccc(-c2nc(-c3ccccc3)nc(-c3cc(-n4c5ccccc5c5c6c(ccc54)sc4ccccc46)ccc3-n3c4ccccc4c4c5c(ccc43)sc3ccccc35)n2)cc1]

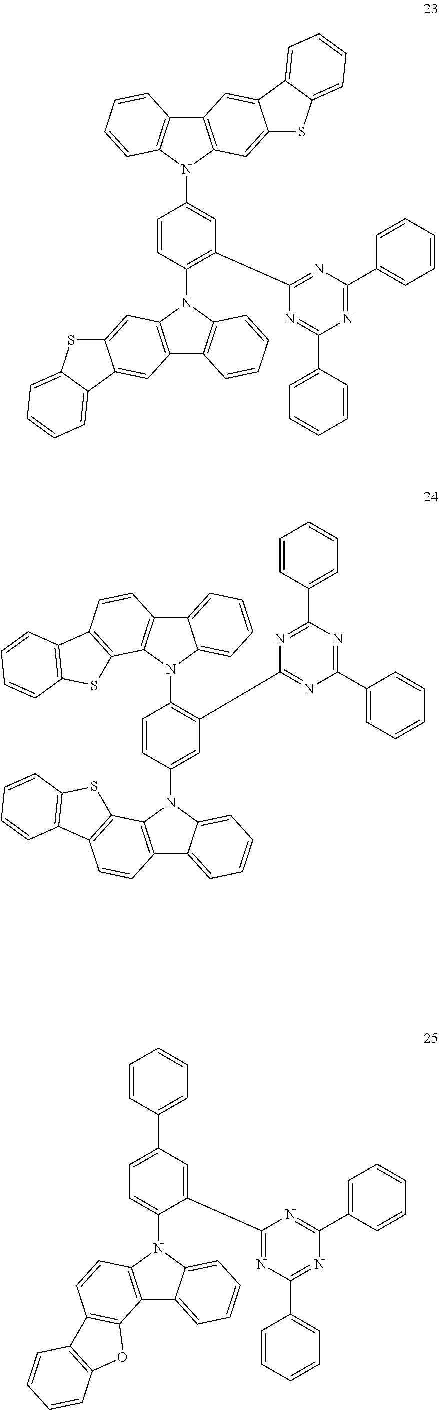 [SMILES: c1ccc(-c2nc(-c3ccccc3)nc(-c3cc(-n4c5ccccc5c5cc6c(cc54)sc4ccccc46)ccc3-n3c4ccccc4c4cc5c(cc43)sc3ccccc35)n2)cc1 ; c1ccc(-c2nc(-c3ccccc3)nc(-c3cc(-n4c5ccccc5c5ccc6c7ccccc7sc6c54)ccc3-n3c4ccccc4c4ccc5c6ccccc6sc5c43)n2)cc1 ; c1ccc(-c2ccc(-n3c4ccccc4c4c5oc6ccccc6c5ccc43)c(-c3nc(-c4ccccc4)nc(-c4ccccc4)n3)c2)cc1]

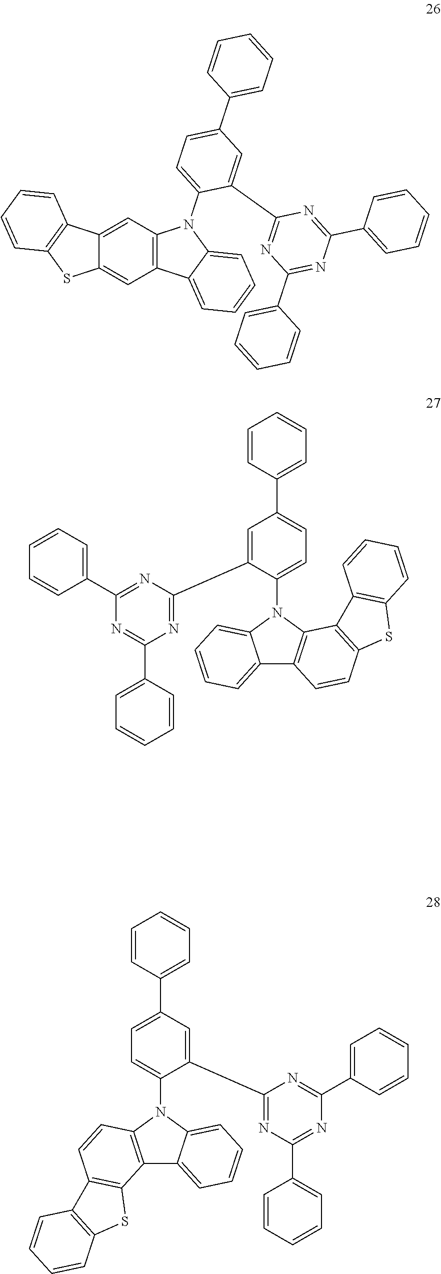 [SMILES: c1ccc(-c2ccc(-n3c4ccccc4c4cc5sc6ccccc6c5cc43)c(-c3nc(-c4ccccc4)nc(-c4ccccc4)n3)c2)cc1 ; c1ccc(-c2ccc(-n3c4ccccc4c4ccc5sc6ccccc6c5c43)c(-c3nc(-c4ccccc4)nc(-c4ccccc4)n3)c2)cc1 ; c1ccc(-c2ccc(-n3c4ccccc4c4c5sc6ccccc6c5ccc43)c(-c3nc(-c4ccccc4)nc(-c4ccccc4)n3)c2)cc1]

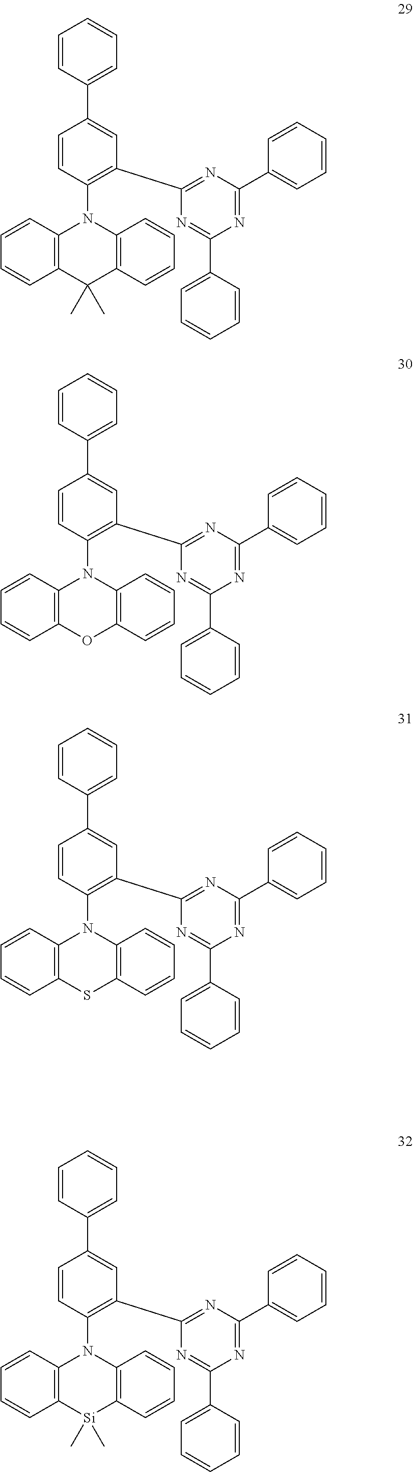 [SMILES: CC1(C)c2ccccc2N(c2ccc(-c3ccccc3)cc2-c2nc(-c3ccccc3)nc(-c3ccccc3)n2)c2ccccc21 ; c1ccc(-c2ccc(N3c4ccccc4Oc4ccccc43)c(-c3nc(-c4ccccc4)nc(-c4ccccc4)n3)c2)cc1 ; c1ccc(-c2ccc(N3c4ccccc4Sc4ccccc43)c(-c3nc(-c4ccccc4)nc(-c4ccccc4)n3)c2)cc1 ; C[Si]1(C)c2ccccc2N(c2ccc(-c3ccccc3)cc2-c2nc(-c3ccccc3)nc(-c3ccccc3)n2)c2ccccc21]

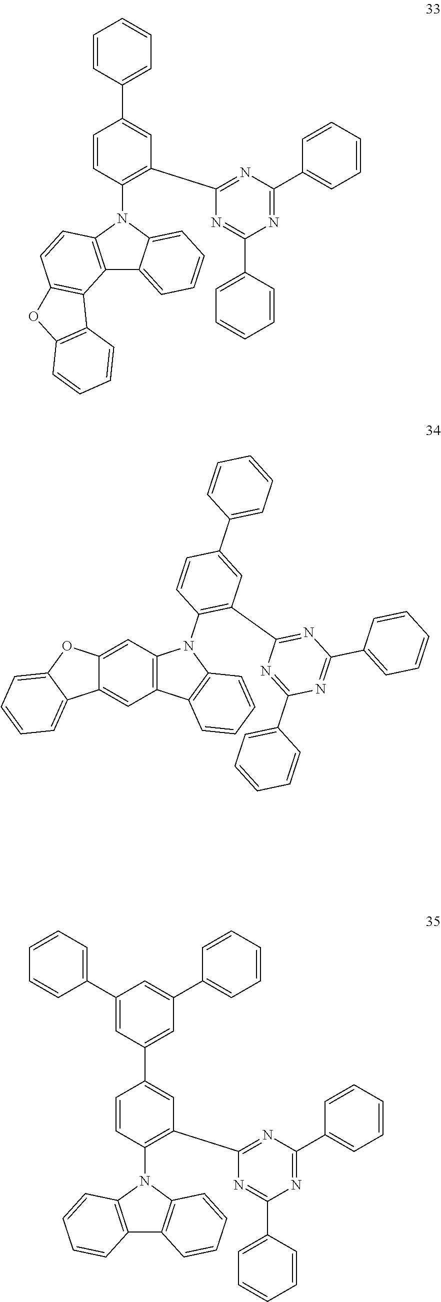 [SMILES: c1ccc(-c2ccc(-n3c4ccccc4c4c5c(ccc43)oc3ccccc35)c(-c3nc(-c4ccccc4)nc(-c4ccccc4)n3)c2)cc1 ; c1ccc(-c2ccc(-n3c4ccccc4c4cc5c(cc43)oc3ccccc35)c(-c3nc(-c4ccccc4)nc(-c4ccccc4)n3)c2)cc1 ; c1ccc(-c2cc(-c3ccccc3)cc(-c3ccc(-n4c5ccccc5c5ccccc54)c(-c4nc(-c5ccccc5)nc(-c5ccccc5)n4)c3)c2)cc1]

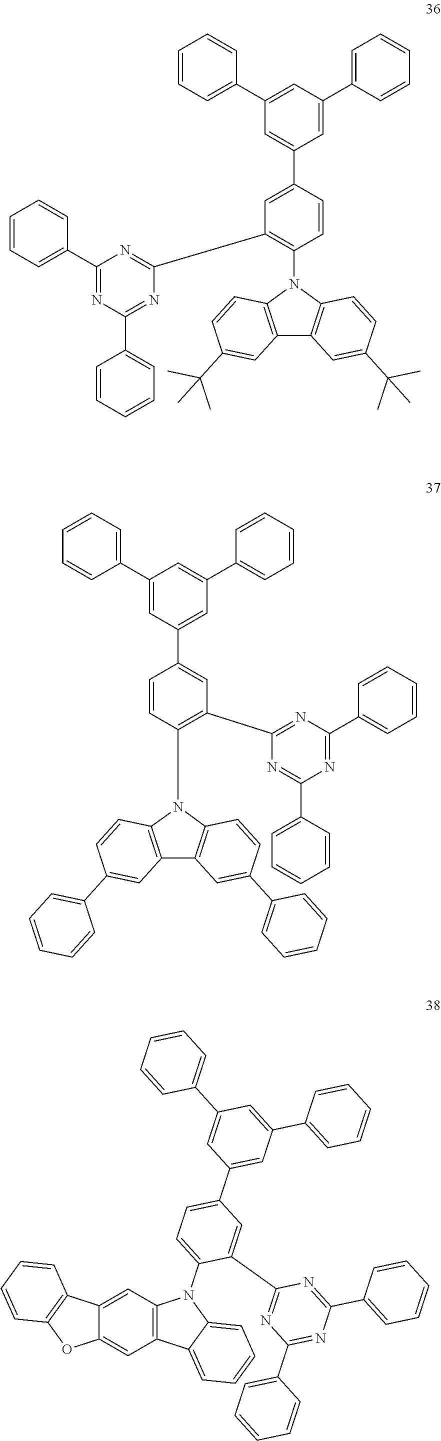 [SMILES: CC(C)(C)c1ccc2c(c1)c1cc(C(C)(C)C)ccc1n2-c1ccc(-c2cc(-c3ccccc3)cc(-c3ccccc3)c2)cc1-c1nc(-c2ccccc2)nc(-c2ccccc2)n1 ; c1ccc(-c2cc(-c3ccccc3)cc(-c3ccc(-n4c5ccc(-c6ccccc6)cc5c5cc(-c6ccccc6)ccc54)c(-c4nc(-c5ccccc5)nc(-c5ccccc5)n4)c3)c2)cc1 ; c1ccc(-c2cc(-c3ccccc3)cc(-c3ccc(-n4c5ccccc5c5cc6oc7ccccc7c6cc54)c(-c4nc(-c5ccccc5)nc(-c5ccccc5)n4)c3)c2)cc1]

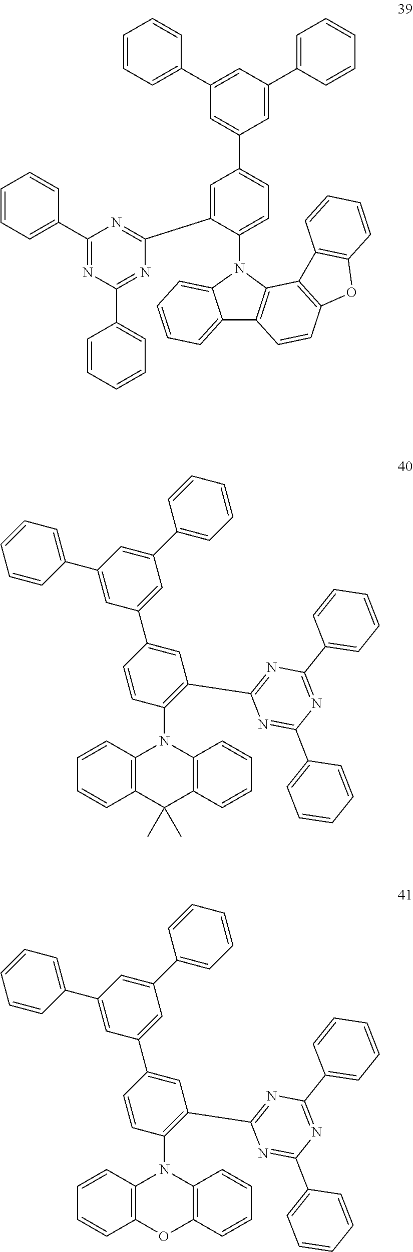 [SMILES: c1ccc(-c2cc(-c3ccccc3)cc(-c3ccc(-n4c5ccccc5c5ccc6oc7ccccc7c6c54)c(-c4nc(-c5ccccc5)nc(-c5ccccc5)n4)c3)c2)cc1 ; CC1(C)c2ccccc2N(c2ccc(-c3cc(-c4ccccc4)cc(-c4ccccc4)c3)cc2-c2nc(-c3ccccc3)nc(-c3ccccc3)n2)c2ccccc21 ; c1ccc(-c2cc(-c3ccccc3)cc(-c3ccc(N4c5ccccc5Oc5ccccc54)c(-c4nc(-c5ccccc5)nc(-c5ccccc5)n4)c3)c2)cc1]

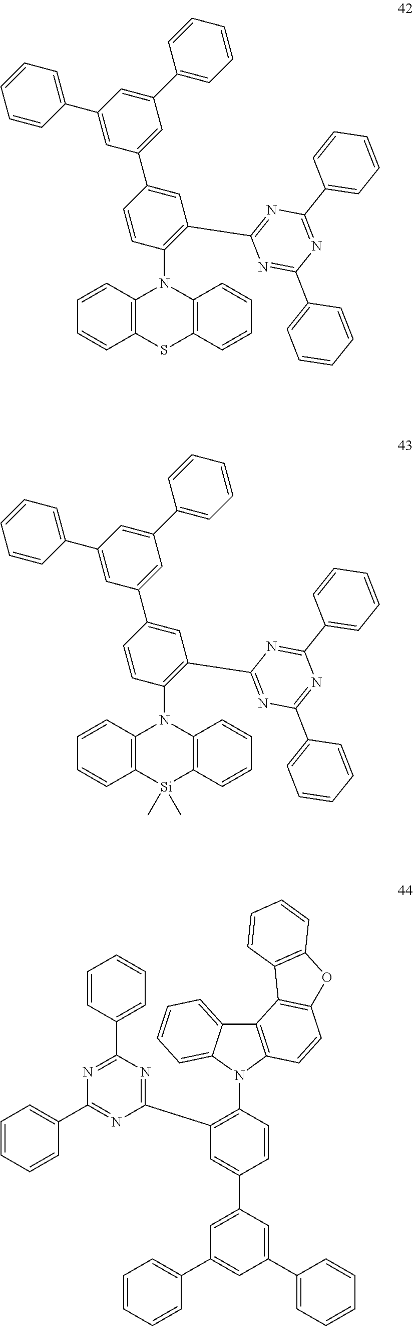 [SMILES: c1ccc(-c2cc(-c3ccccc3)cc(-c3ccc(N4c5ccccc5Sc5ccccc54)c(-c4nc(-c5ccccc5)nc(-c5ccccc5)n4)c3)c2)cc1 ; C[Si]1(C)c2ccccc2N(c2ccc(-c3cc(-c4ccccc4)cc(-c4ccccc4)c3)cc2-c2nc(-c3ccccc3)nc(-c3ccccc3)n2)c2ccccc21 ; c1ccc(-c2cc(-c3ccccc3)cc(-c3ccc(-n4c5ccccc5c5c6c(ccc54)oc4ccccc46)c(-c4nc(-c5ccccc5)nc(-c5ccccc5)n4)c3)c2)cc1]

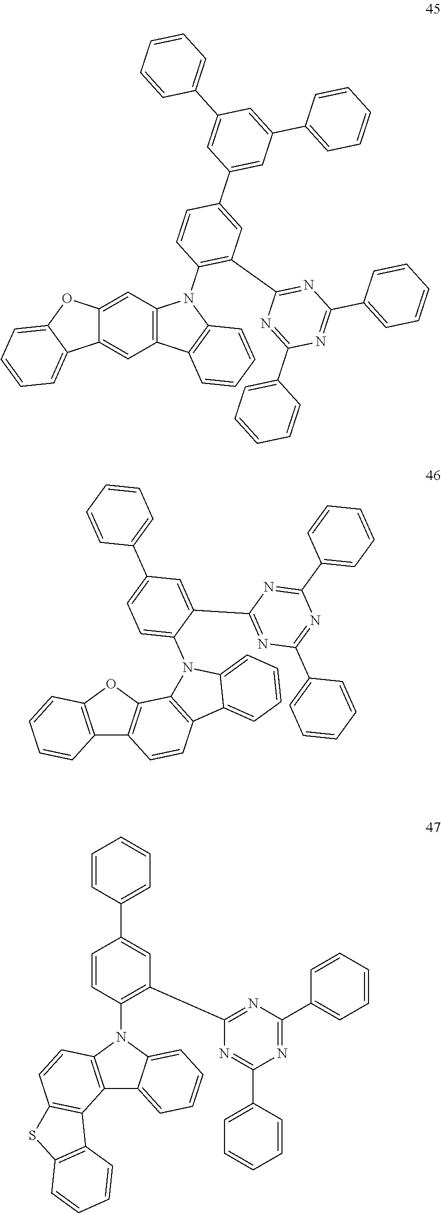 [SMILES: c1ccc(-c2cc(-c3ccccc3)cc(-c3ccc(-n4c5ccccc5c5cc6c(cc54)oc4ccccc46)c(-c4nc(-c5ccccc5)nc(-c5ccccc5)n4)c3)c2)cc1 ; c1ccc(-c2ccc(-n3c4ccccc4c4ccc5c6ccccc6oc5c43)c(-c3nc(-c4ccccc4)nc(-c4ccccc4)n3)c2)cc1 ; c1ccc(-c2ccc(-n3c4ccccc4c4c5c(ccc43)sc3ccccc35)c(-c3nc(-c4ccccc4)nc(-c4ccccc4)n3)c2)cc1]

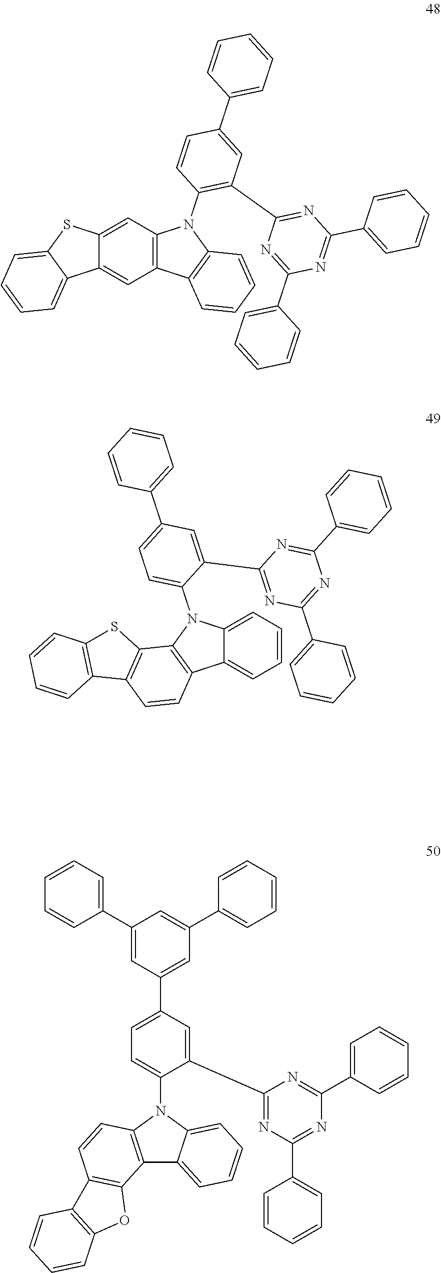 [SMILES: c1ccc(-c2ccc(-n3c4ccccc4c4cc5c(cc43)sc3ccccc35)c(-c3nc(-c4ccccc4)nc(-c4ccccc4)n3)c2)cc1 ; c1ccc(-c2ccc(-n3c4ccccc4c4ccc5c6ccccc6sc5c43)c(-c3nc(-c4ccccc4)nc(-c4ccccc4)n3)c2)cc1 ; c1ccc(-c2cc(-c3ccccc3)cc(-c3ccc(-n4c5ccccc5c5c6oc7ccccc7c6ccc54)c(-c4nc(-c5ccccc5)nc(-c5ccccc5)n4)c3)c2)cc1]

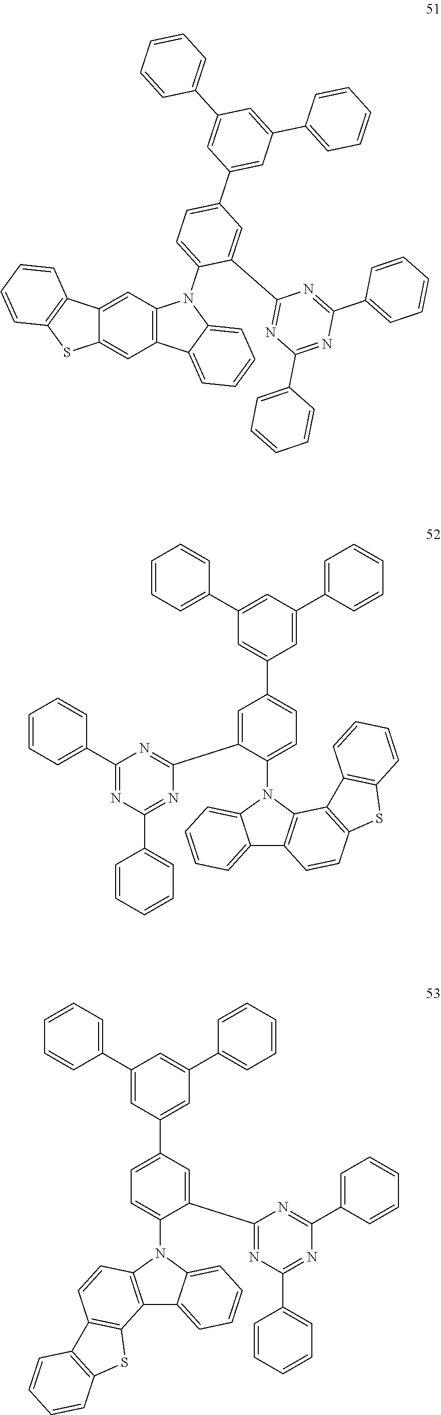 [SMILES: c1ccc(-c2cc(-c3ccccc3)cc(-c3ccc(-n4c5ccccc5c5cc6sc7ccccc7c6cc54)c(-c4nc(-c5ccccc5)nc(-c5ccccc5)n4)c3)c2)cc1 ; c1ccc(-c2cc(-c3ccccc3)cc(-c3ccc(-n4c5ccccc5c5ccc6sc7ccccc7c6c54)c(-c4nc(-c5ccccc5)nc(-c5ccccc5)n4)c3)c2)cc1 ; c1ccc(-c2cc(-c3ccccc3)cc(-c3ccc(-n4c5ccccc5c5c6sc7ccccc7c6ccc54)c(-c4nc(-c5ccccc5)nc(-c5ccccc5)n4)c3)c2)cc1]

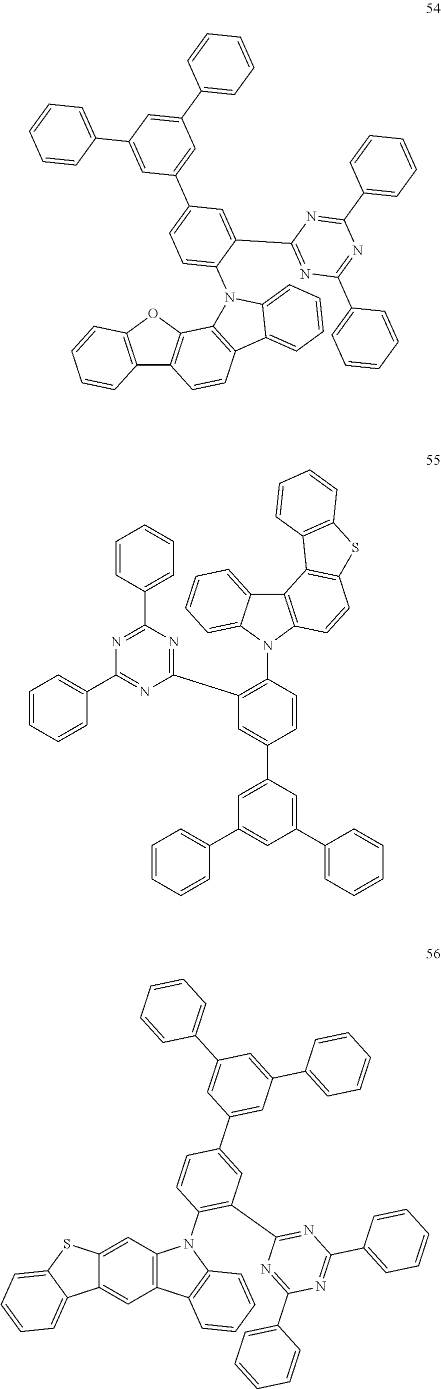 [SMILES: c1ccc(-c2cc(-c3ccccc3)cc(-c3ccc(-n4c5ccccc5c5ccc6c7ccccc7oc6c54)c(-c4nc(-c5ccccc5)nc(-c5ccccc5)n4)c3)c2)cc1 ; c1ccc(-c2cc(-c3ccccc3)cc(-c3ccc(-n4c5ccccc5c5c6c(ccc54)sc4ccccc46)c(-c4nc(-c5ccccc5)nc(-c5ccccc5)n4)c3)c2)cc1 ; c1ccc(-c2cc(-c3ccccc3)cc(-c3ccc(-n4c5ccccc5c5cc6c(cc54)sc4ccccc46)c(-c4nc(-c5ccccc5)nc(-c5ccccc5)n4)c3)c2)cc1]

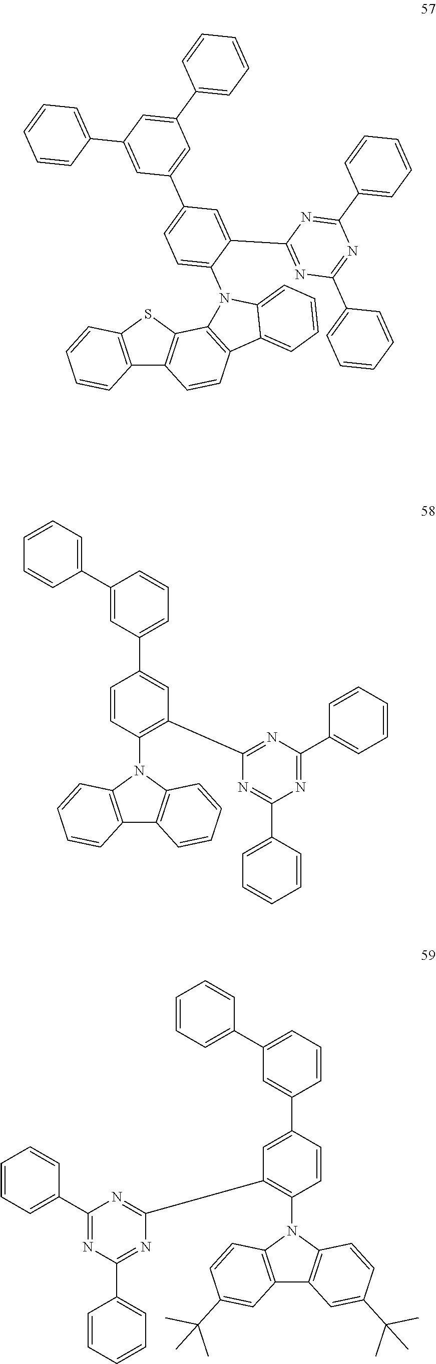 [SMILES: c1ccc(-c2cc(-c3ccccc3)cc(-c3ccc(-n4c5ccccc5c5ccc6c7ccccc7sc6c54)c(-c4nc(-c5ccccc5)nc(-c5ccccc5)n4)c3)c2)cc1 ; c1ccc(-c2cccc(-c3ccc(-n4c5ccccc5c5ccccc54)c(-c4nc(-c5ccccc5)nc(-c5ccccc5)n4)c3)c2)cc1 ; CC(C)(C)c1ccc2c(c1)c1cc(C(C)(C)C)ccc1n2-c1ccc(-c2cccc(-c3ccccc3)c2)cc1-c1nc(-c2ccccc2)nc(-c2ccccc2)n1]

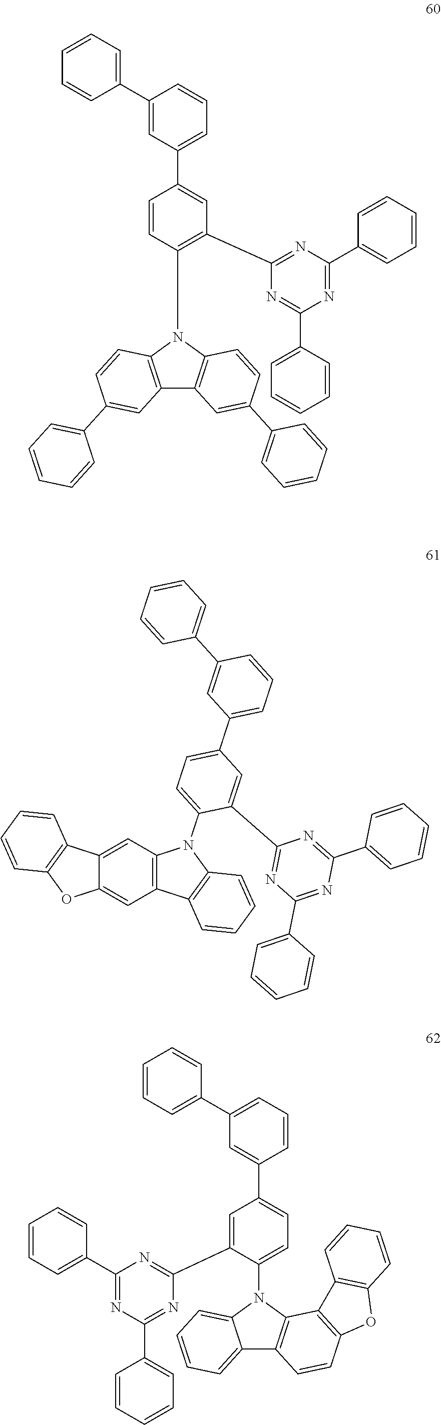 [SMILES: c1ccc(-c2cccc(-c3ccc(-n4c5ccc(-c6ccccc6)cc5c5cc(-c6ccccc6)ccc54)c(-c4nc(-c5ccccc5)nc(-c5ccccc5)n4)c3)c2)cc1 ; c1ccc(-c2cccc(-c3ccc(-n4c5ccccc5c5cc6oc7ccccc7c6cc54)c(-c4nc(-c5ccccc5)nc(-c5ccccc5)n4)c3)c2)cc1 ; c1ccc(-c2cccc(-c3ccc(-n4c5ccccc5c5ccc6oc7ccccc7c6c54)c(-c4nc(-c5ccccc5)nc(-c5ccccc5)n4)c3)c2)cc1]

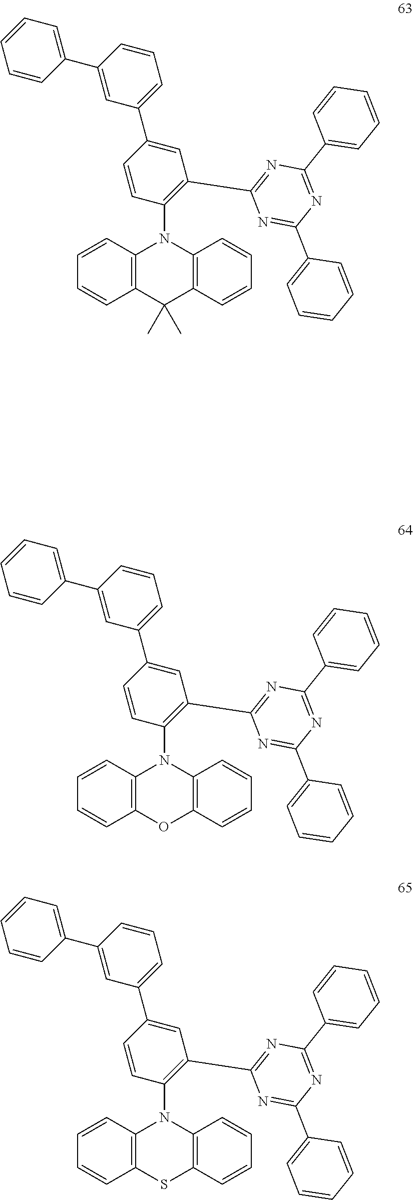 [SMILES: CC1(C)c2ccccc2N(c2ccc(-c3cccc(-c4ccccc4)c3)cc2-c2nc(-c3ccccc3)nc(-c3ccccc3)n2)c2ccccc21 ; c1ccc(-c2cccc(-c3ccc(N4c5ccccc5Oc5ccccc54)c(-c4nc(-c5ccccc5)nc(-c5ccccc5)n4)c3)c2)cc1 ; c1ccc(-c2cccc(-c3ccc(N4c5ccccc5Sc5ccccc54)c(-c4nc(-c5ccccc5)nc(-c5ccccc5)n4)c3)c2)cc1]

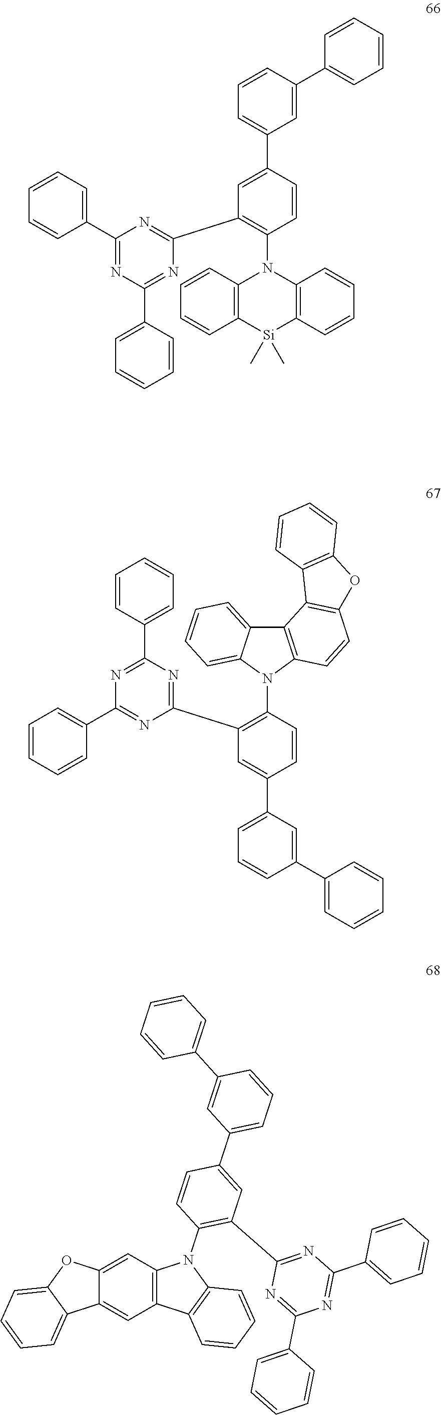 [SMILES: C[Si]1(C)c2ccccc2N(c2ccc(-c3cccc(-c4ccccc4)c3)cc2-c2nc(-c3ccccc3)nc(-c3ccccc3)n2)c2ccccc21 ; c1ccc(-c2cccc(-c3ccc(-n4c5ccccc5c5c6c(ccc54)oc4ccccc46)c(-c4nc(-c5ccccc5)nc(-c5ccccc5)n4)c3)c2)cc1 ; c1ccc(-c2cccc(-c3ccc(-n4c5ccccc5c5cc6c(cc54)oc4ccccc46)c(-c4nc(-c5ccccc5)nc(-c5ccccc5)n4)c3)c2)cc1]

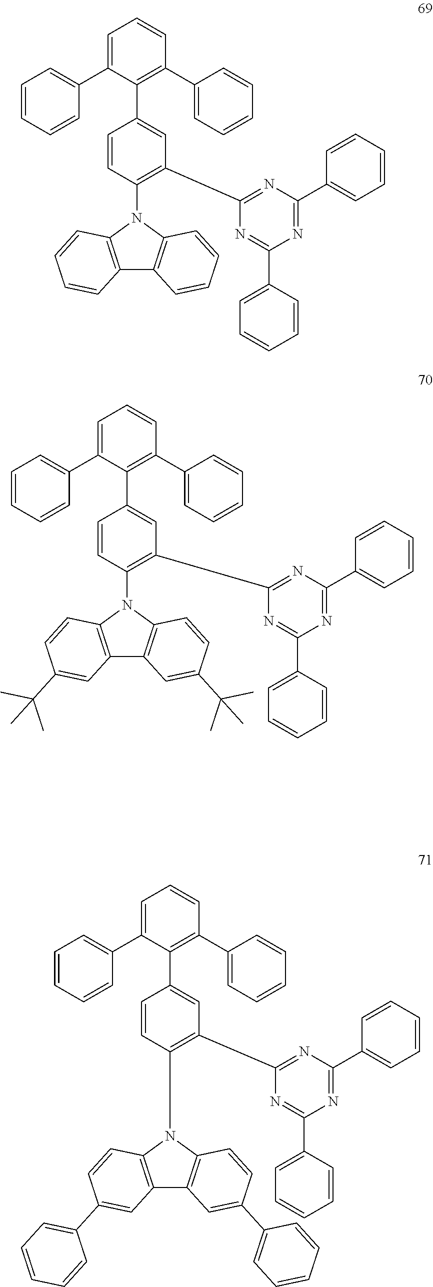 [SMILES: c1ccc(-c2nc(-c3ccccc3)nc(-c3cc(-c4c(-c5ccccc5)cccc4-c4ccccc4)ccc3-n3c4ccccc4c4ccccc43)n2)cc1 ; CC(C)(C)c1ccc2c(c1)c1cc(C(C)(C)C)ccc1n2-c1ccc(-c2c(-c3ccccc3)cccc2-c2ccccc2)cc1-c1nc(-c2ccccc2)nc(-c2ccccc2)n1 ; c1ccc(-c2ccc3c(c2)c2cc(-c4ccccc4)ccc2n3-c2ccc(-c3c(-c4ccccc4)cccc3-c3ccccc3)cc2-c2nc(-c3ccccc3)nc(-c3ccccc3)n2)cc1]

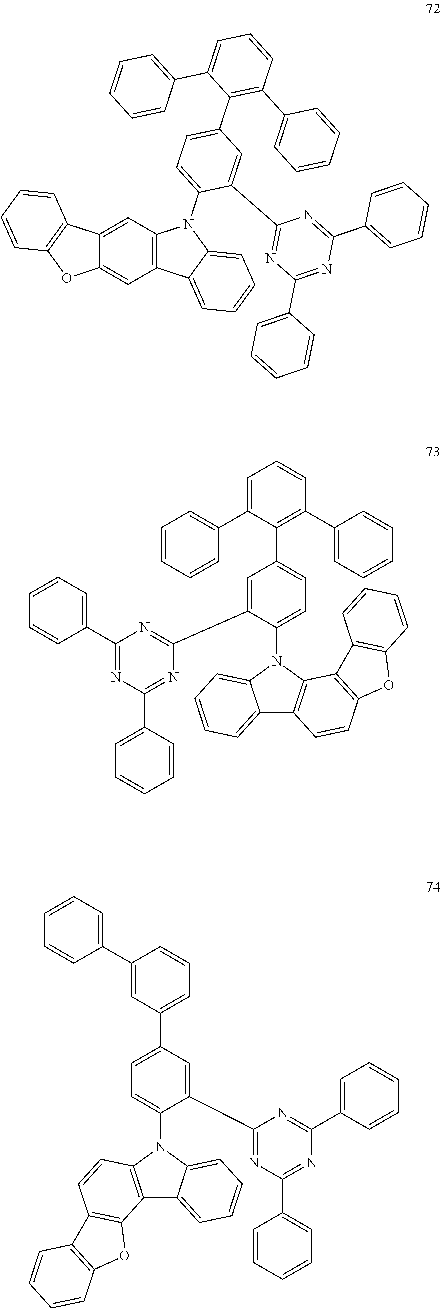 [SMILES: c1ccc(-c2nc(-c3ccccc3)nc(-c3cc(-c4c(-c5ccccc5)cccc4-c4ccccc4)ccc3-n3c4ccccc4c4cc5oc6ccccc6c5cc43)n2)cc1 ; c1ccc(-c2nc(-c3ccccc3)nc(-c3cc(-c4c(-c5ccccc5)cccc4-c4ccccc4)ccc3-n3c4ccccc4c4ccc5oc6ccccc6c5c43)n2)cc1 ; c1ccc(-c2cccc(-c3ccc(-n4c5ccccc5c5c6oc7ccccc7c6ccc54)c(-c4nc(-c5ccccc5)nc(-c5ccccc5)n4)c3)c2)cc1]

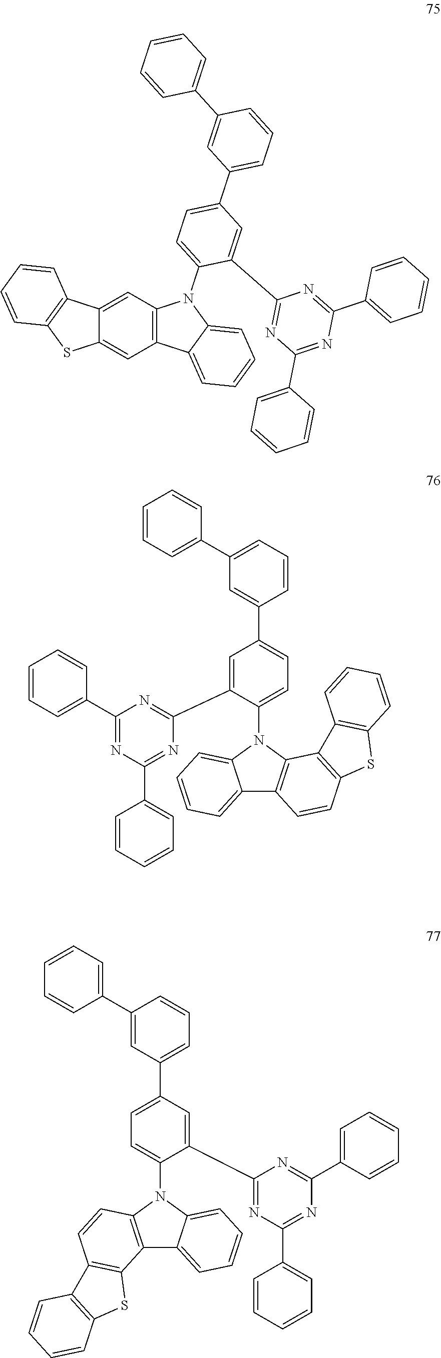 [SMILES: c1ccc(-c2cccc(-c3ccc(-n4c5ccccc5c5cc6sc7ccccc7c6cc54)c(-c4nc(-c5ccccc5)nc(-c5ccccc5)n4)c3)c2)cc1 ; c1ccc(-c2cccc(-c3ccc(-n4c5ccccc5c5ccc6sc7ccccc7c6c54)c(-c4nc(-c5ccccc5)nc(-c5ccccc5)n4)c3)c2)cc1 ; c1ccc(-c2cccc(-c3ccc(-n4c5ccccc5c5c6sc7ccccc7c6ccc54)c(-c4nc(-c5ccccc5)nc(-c5ccccc5)n4)c3)c2)cc1]

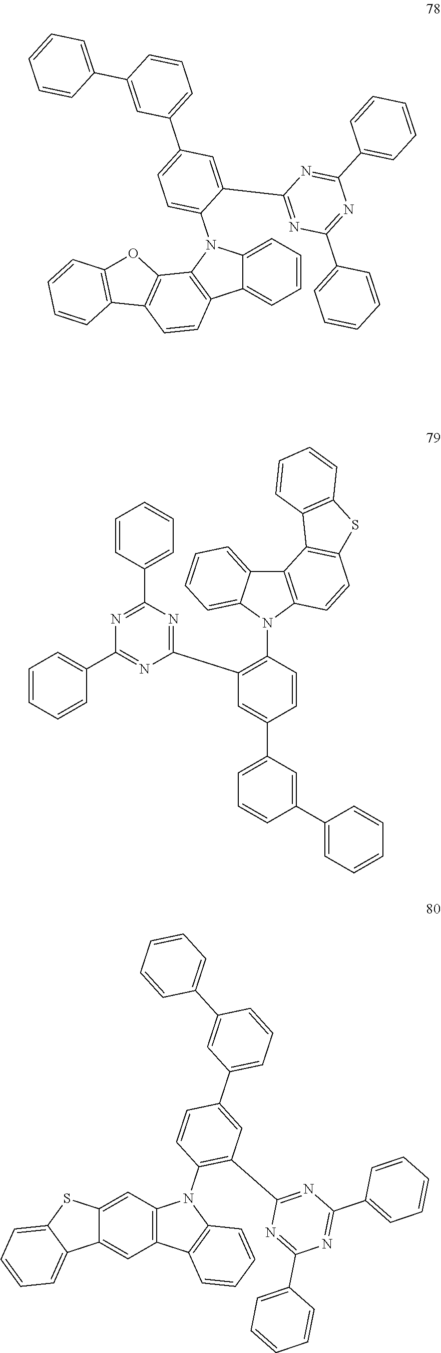 [SMILES: c1ccc(-c2cccc(-c3ccc(-n4c5ccccc5c5ccc6c7ccccc7oc6c54)c(-c4nc(-c5ccccc5)nc(-c5ccccc5)n4)c3)c2)cc1 ; c1ccc(-c2cccc(-c3ccc(-n4c5ccccc5c5c6c(ccc54)sc4ccccc46)c(-c4nc(-c5ccccc5)nc(-c5ccccc5)n4)c3)c2)cc1 ; c1ccc(-c2cccc(-c3ccc(-n4c5ccccc5c5cc6c(cc54)sc4ccccc46)c(-c4nc(-c5ccccc5)nc(-c5ccccc5)n4)c3)c2)cc1]

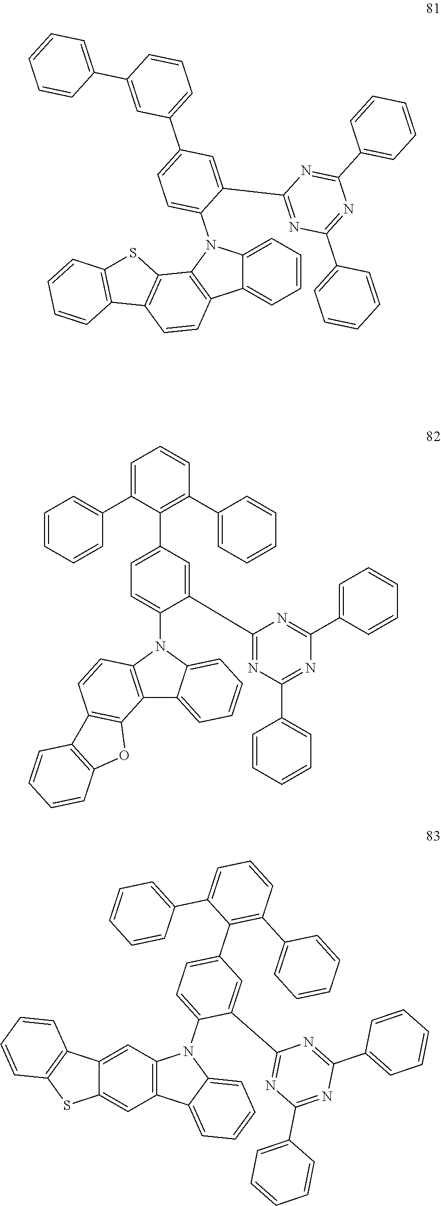 [SMILES: c1ccc(-c2cccc(-c3ccc(-n4c5ccccc5c5ccc6c7ccccc7sc6c54)c(-c4nc(-c5ccccc5)nc(-c5ccccc5)n4)c3)c2)cc1 ; c1ccc(-c2nc(-c3ccccc3)nc(-c3cc(-c4c(-c5ccccc5)cccc4-c4ccccc4)ccc3-n3c4ccccc4c4c5oc6ccccc6c5ccc43)n2)cc1 ; c1ccc(-c2nc(-c3ccccc3)nc(-c3cc(-c4c(-c5ccccc5)cccc4-c4ccccc4)ccc3-n3c4ccccc4c4cc5sc6ccccc6c5cc43)n2)cc1]

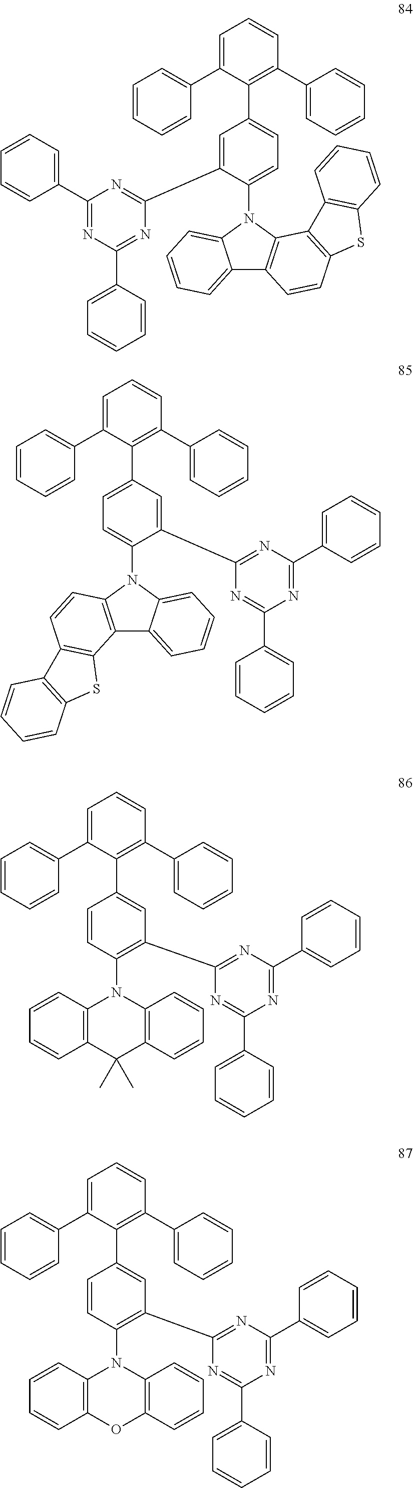

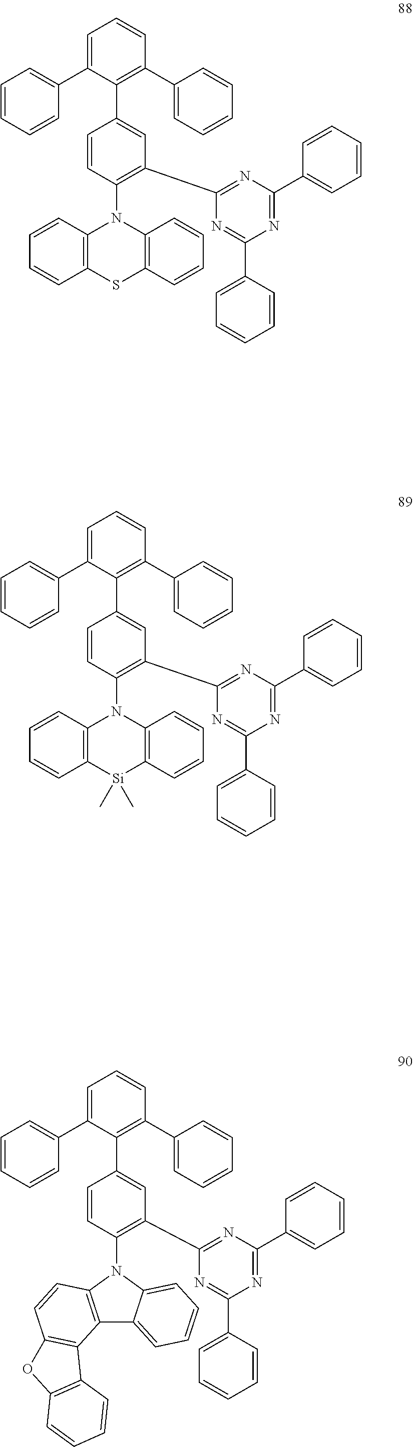 [SMILES: c1ccc(-c2nc(-c3ccccc3)nc(-c3cc(-c4c(-c5ccccc5)cccc4-c4ccccc4)ccc3N3c4ccccc4Sc4ccccc43)n2)cc1 ; C[Si]1(C)c2ccccc2N(c2ccc(-c3c(-c4ccccc4)cccc3-c3ccccc3)cc2-c2nc(-c3ccccc3)nc(-c3ccccc3)n2)c2ccccc21 ; c1ccc(-c2nc(-c3ccccc3)nc(-c3cc(-c4c(-c5ccccc5)cccc4-c4ccccc4)ccc3-n3c4ccccc4c4c5c(ccc43)oc3ccccc35)n2)cc1]

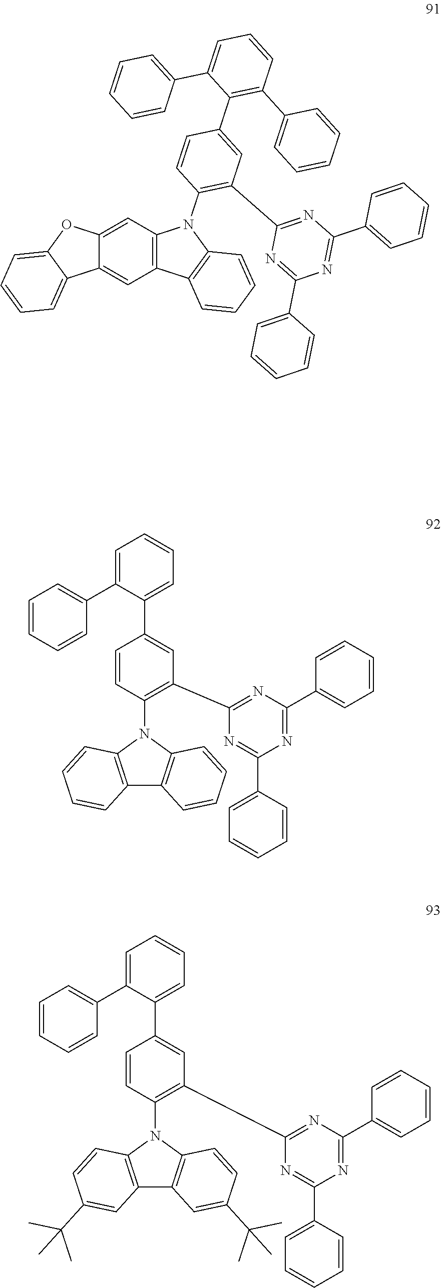 [SMILES: c1ccc(-c2nc(-c3ccccc3)nc(-c3cc(-c4c(-c5ccccc5)cccc4-c4ccccc4)ccc3-n3c4ccccc4c4cc5c(cc43)oc3ccccc35)n2)cc1 ; c1ccc(-c2nc(-c3ccccc3)nc(-c3cc(-c4ccccc4-c4ccccc4)ccc3-n3c4ccccc4c4ccccc43)n2)cc1 ; CC(C)(C)c1ccc2c(c1)c1cc(C(C)(C)C)ccc1n2-c1ccc(-c2ccccc2-c2ccccc2)cc1-c1nc(-c2ccccc2)nc(-c2ccccc2)n1]

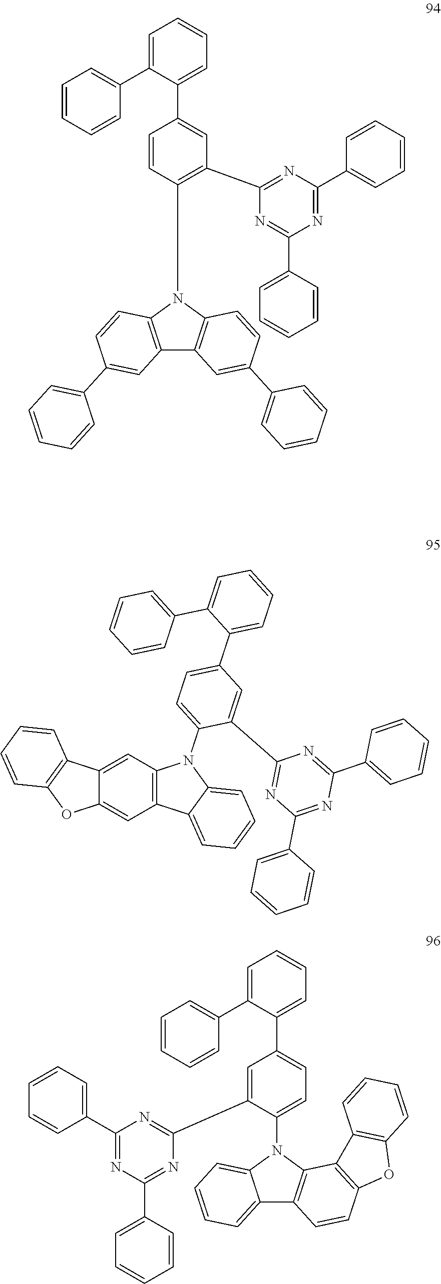

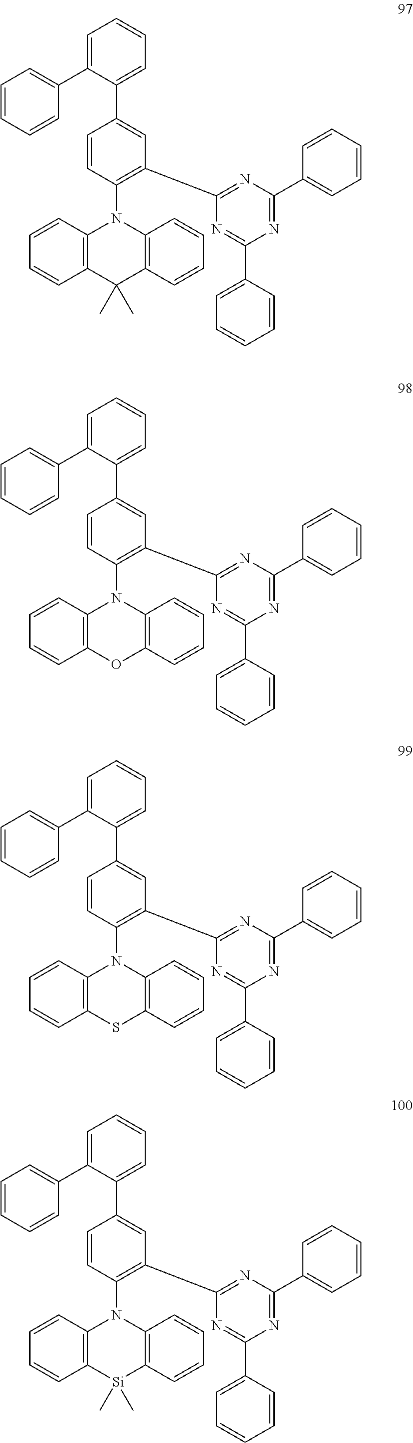 [SMILES: CC1(C)c2ccccc2N(c2ccc(-c3ccccc3-c3ccccc3)cc2-c2nc(-c3ccccc3)nc(-c3ccccc3)n2)c2ccccc21 ; c1ccc(-c2nc(-c3ccccc3)nc(-c3cc(-c4ccccc4-c4ccccc4)ccc3N3c4ccccc4Oc4ccccc43)n2)cc1 ; c1ccc(-c2nc(-c3ccccc3)nc(-c3cc(-c4ccccc4-c4ccccc4)ccc3N3c4ccccc4Sc4ccccc43)n2)cc1 ; C[Si]1(C)c2ccccc2N(c2ccc(-c3ccccc3-c3ccccc3)cc2-c2nc(-c3ccccc3)nc(-c3ccccc3)n2)c2ccccc21]

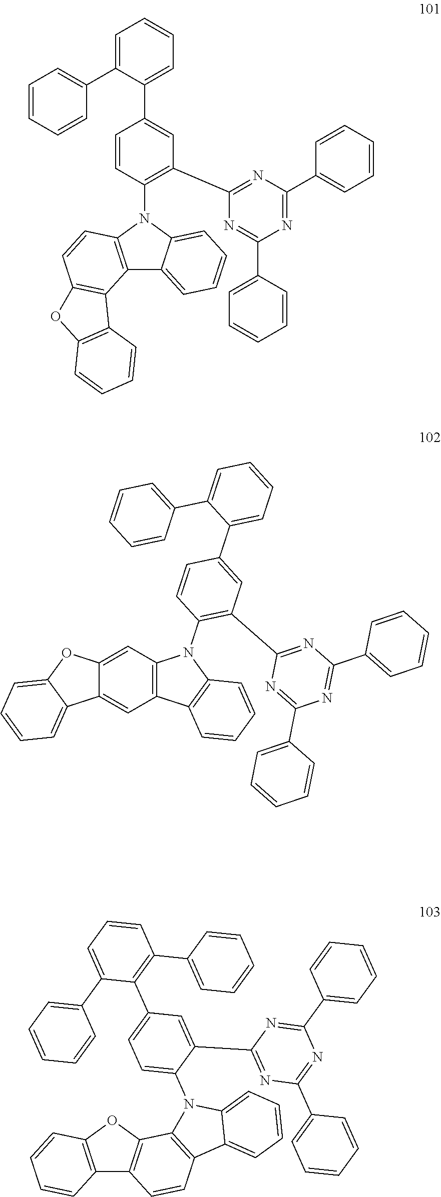 [SMILES: c1ccc(-c2nc(-c3ccccc3)nc(-c3cc(-c4ccccc4-c4ccccc4)ccc3-n3c4ccccc4c4c5c(ccc43)oc3ccccc35)n2)cc1 ; c1ccc(-c2nc(-c3ccccc3)nc(-c3cc(-c4ccccc4-c4ccccc4)ccc3-n3c4ccccc4c4cc5c(cc43)oc3ccccc35)n2)cc1 ; c1ccc(-c2nc(-c3ccccc3)nc(-c3cc(-c4c(-c5ccccc5)cccc4-c4ccccc4)ccc3-n3c4ccccc4c4ccc5c6ccccc6oc5c43)n2)cc1]

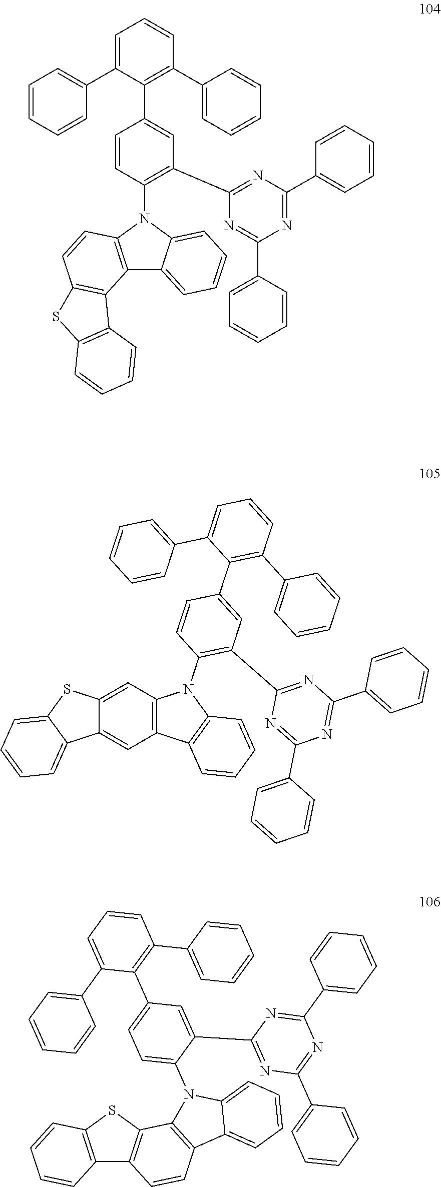 [SMILES: c1ccc(-c2nc(-c3ccccc3)nc(-c3cc(-c4c(-c5ccccc5)cccc4-c4ccccc4)ccc3-n3c4ccccc4c4c5c(ccc43)sc3ccccc35)n2)cc1 ; c1ccc(-c2nc(-c3ccccc3)nc(-c3cc(-c4c(-c5ccccc5)cccc4-c4ccccc4)ccc3-n3c4ccccc4c4cc5c(cc43)sc3ccccc35)n2)cc1 ; c1ccc(-c2nc(-c3ccccc3)nc(-c3cc(-c4c(-c5ccccc5)cccc4-c4ccccc4)ccc3-n3c4ccccc4c4ccc5c6ccccc6sc5c43)n2)cc1]

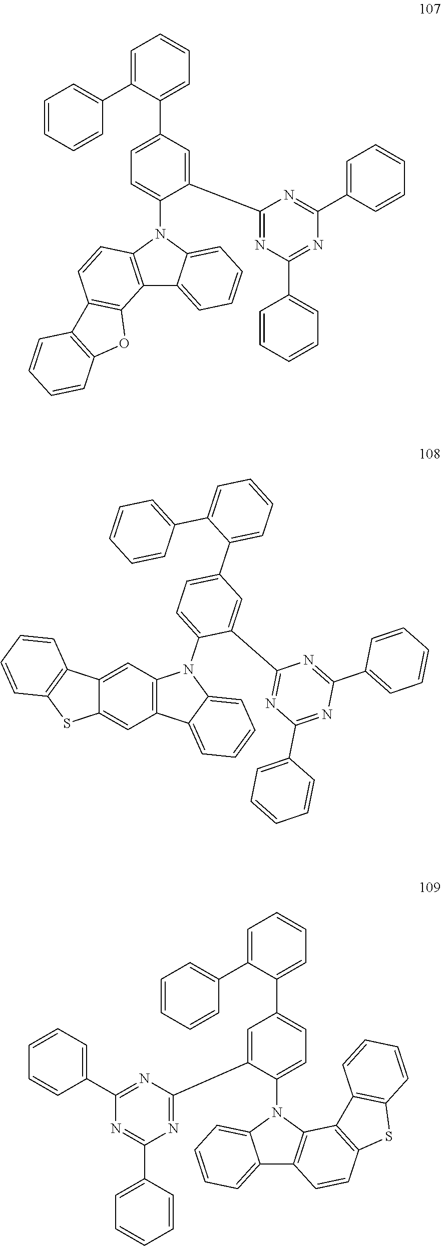 [SMILES: c1ccc(-c2nc(-c3ccccc3)nc(-c3cc(-c4ccccc4-c4ccccc4)ccc3-n3c4ccccc4c4c5oc6ccccc6c5ccc43)n2)cc1 ; c1ccc(-c2nc(-c3ccccc3)nc(-c3cc(-c4ccccc4-c4ccccc4)ccc3-n3c4ccccc4c4cc5sc6ccccc6c5cc43)n2)cc1 ; c1ccc(-c2nc(-c3ccccc3)nc(-c3cc(-c4ccccc4-c4ccccc4)ccc3-n3c4ccccc4c4ccc5sc6ccccc6c5c43)n2)cc1]

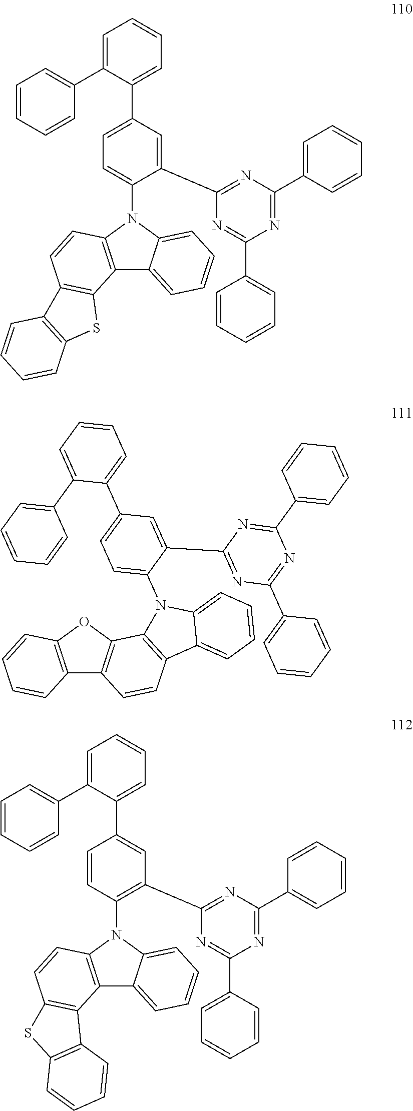

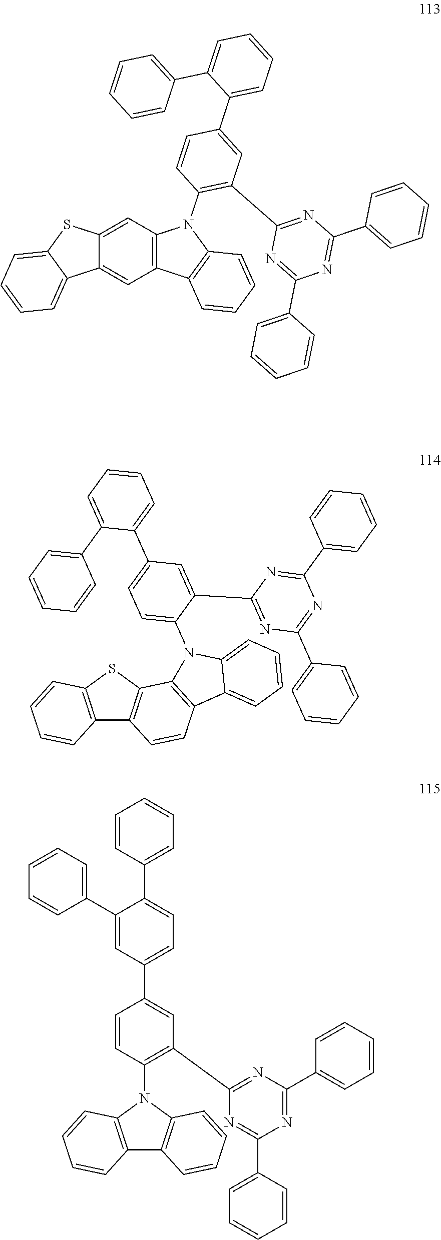 [SMILES: c1ccc(-c2nc(-c3ccccc3)nc(-c3cc(-c4ccccc4-c4ccccc4)ccc3-n3c4ccccc4c4cc5c(cc43)sc3ccccc35)n2)cc1 ; c1ccc(-c2nc(-c3ccccc3)nc(-c3cc(-c4ccccc4-c4ccccc4)ccc3-n3c4ccccc4c4ccc5c6ccccc6sc5c43)n2)cc1 ; c1ccc(-c2nc(-c3ccccc3)nc(-c3cc(-c4ccc(-c5ccccc5)c(-c5ccccc5)c4)ccc3-n3c4ccccc4c4ccccc43)n2)cc1]

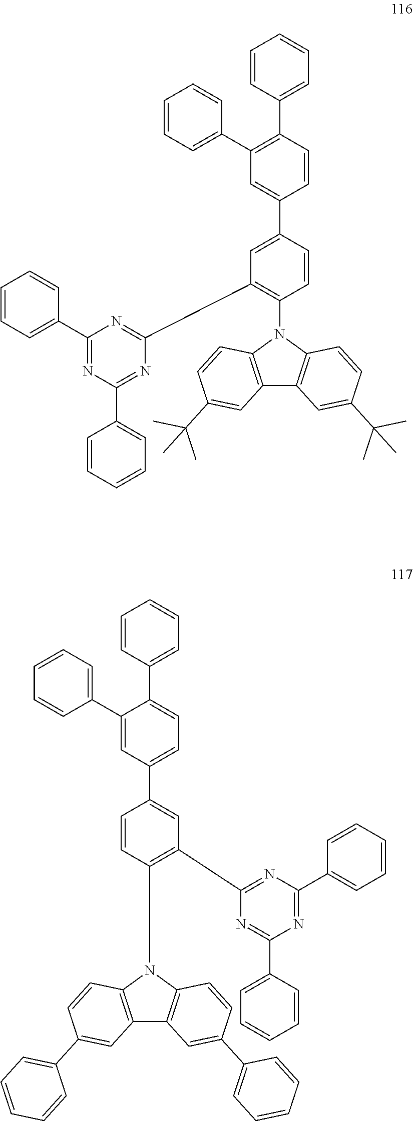 [SMILES: CC(C)(C)c1ccc2c(c1)c1cc(C(C)(C)C)ccc1n2-c1ccc(-c2ccc(-c3ccccc3)c(-c3ccccc3)c2)cc1-c1nc(-c2ccccc2)nc(-c2ccccc2)n1 ; c1ccc(-c2ccc3c(c2)c2cc(-c4ccccc4)ccc2n3-c2ccc(-c3ccc(-c4ccccc4)c(-c4ccccc4)c3)cc2-c2nc(-c3ccccc3)nc(-c3ccccc3)n2)cc1]

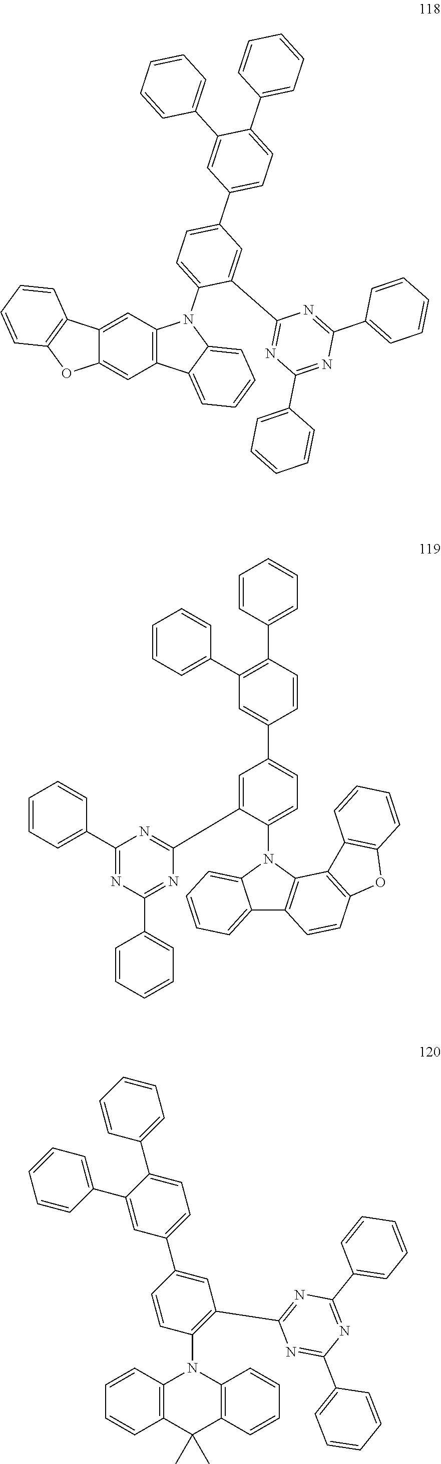 [SMILES: c1ccc(-c2nc(-c3ccccc3)nc(-c3cc(-c4ccc(-c5ccccc5)c(-c5ccccc5)c4)ccc3-n3c4ccccc4c4cc5oc6ccccc6c5cc43)n2)cc1 ; c1ccc(-c2nc(-c3ccccc3)nc(-c3cc(-c4ccc(-c5ccccc5)c(-c5ccccc5)c4)ccc3-n3c4ccccc4c4ccc5oc6ccccc6c5c43)n2)cc1 ; CC1(C)c2ccccc2N(c2ccc(-c3ccc(-c4ccccc4)c(-c4ccccc4)c3)cc2-c2nc(-c3ccccc3)nc(-c3ccccc3)n2)c2ccccc21]

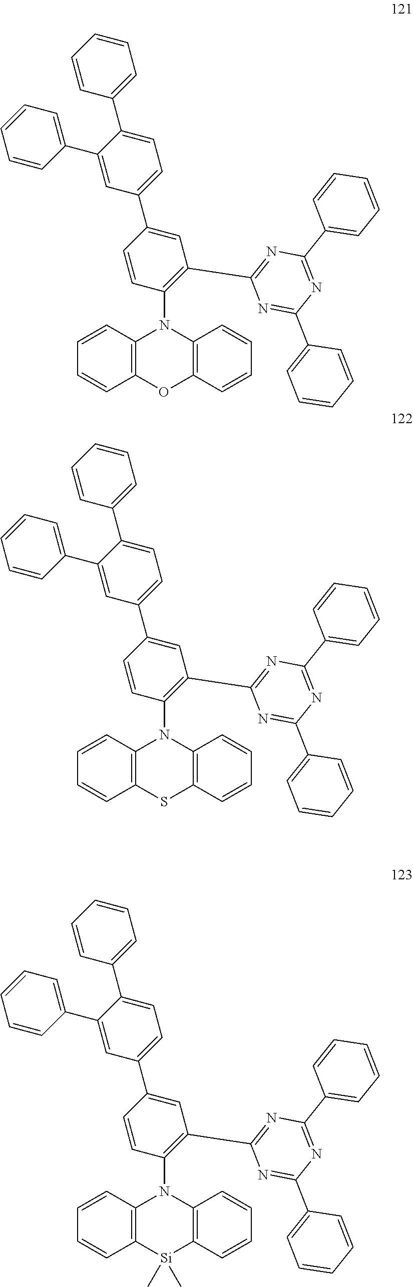 [SMILES: c1ccc(-c2nc(-c3ccccc3)nc(-c3cc(-c4ccc(-c5ccccc5)c(-c5ccccc5)c4)ccc3N3c4ccccc4Oc4ccccc43)n2)cc1 ; c1ccc(-c2nc(-c3ccccc3)nc(-c3cc(-c4ccc(-c5ccccc5)c(-c5ccccc5)c4)ccc3N3c4ccccc4Sc4ccccc43)n2)cc1 ; C[Si]1(C)c2ccccc2N(c2ccc(-c3ccc(-c4ccccc4)c(-c4ccccc4)c3)cc2-c2nc(-c3ccccc3)nc(-c3ccccc3)n2)c2ccccc21]

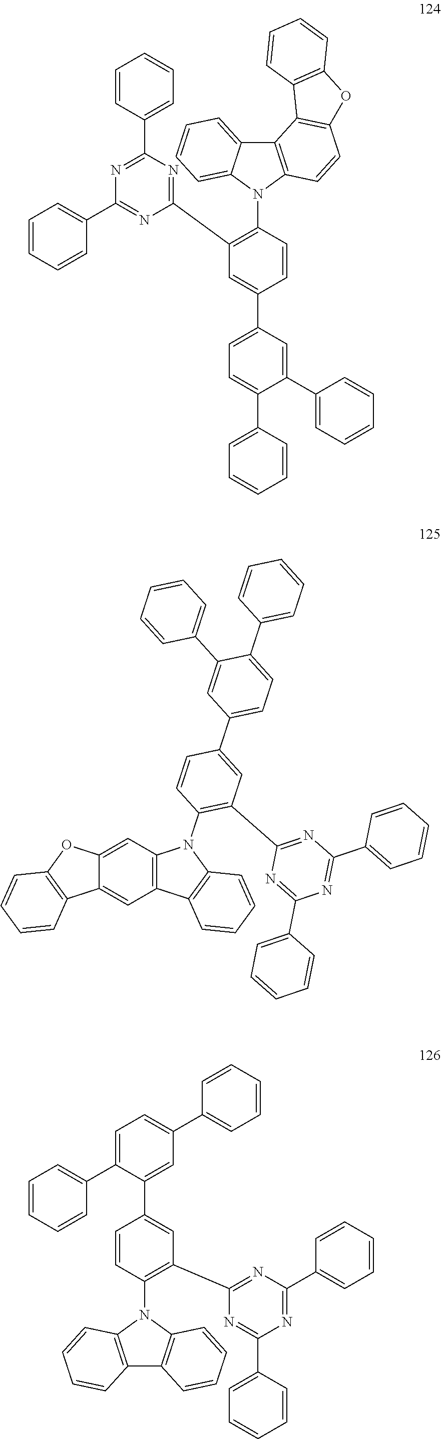 [SMILES: c1ccc(-c2nc(-c3ccccc3)nc(-c3cc(-c4ccc(-c5ccccc5)c(-c5ccccc5)c4)ccc3-n3c4ccccc4c4c5c(ccc43)oc3ccccc35)n2)cc1 ; c1ccc(-c2nc(-c3ccccc3)nc(-c3cc(-c4ccc(-c5ccccc5)c(-c5ccccc5)c4)ccc3-n3c4ccccc4c4cc5c(cc43)oc3ccccc35)n2)cc1 ; c1ccc(-c2ccc(-c3ccccc3)c(-c3ccc(-n4c5ccccc5c5ccccc54)c(-c4nc(-c5ccccc5)nc(-c5ccccc5)n4)c3)c2)cc1]

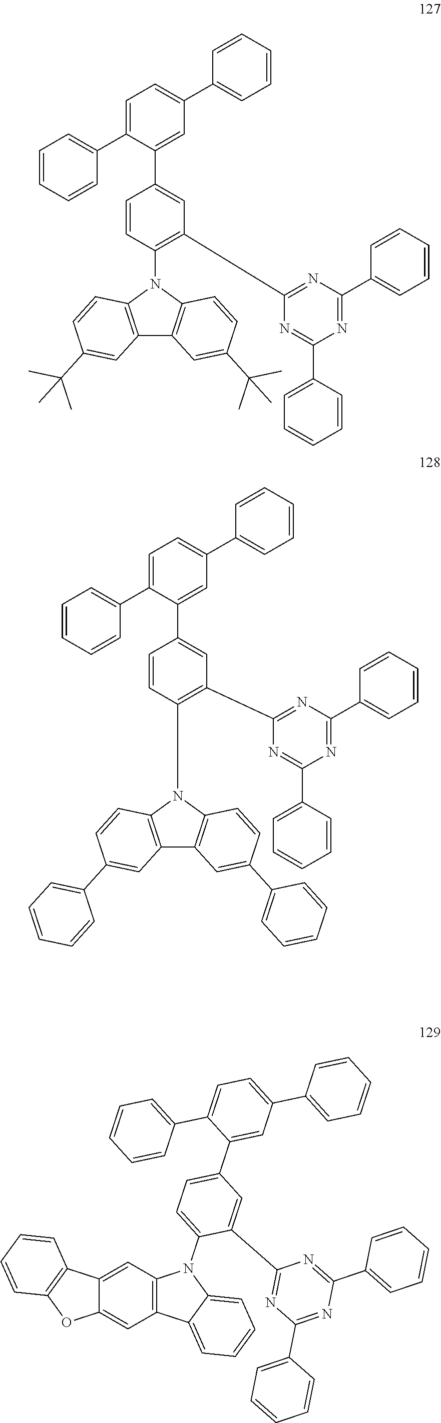 [SMILES: CC(C)(C)c1ccc2c(c1)c1cc(C(C)(C)C)ccc1n2-c1ccc(-c2cc(-c3ccccc3)ccc2-c2ccccc2)cc1-c1nc(-c2ccccc2)nc(-c2ccccc2)n1 ; c1ccc(-c2ccc(-c3ccccc3)c(-c3ccc(-n4c5ccc(-c6ccccc6)cc5c5cc(-c6ccccc6)ccc54)c(-c4nc(-c5ccccc5)nc(-c5ccccc5)n4)c3)c2)cc1 ; c1ccc(-c2ccc(-c3ccccc3)c(-c3ccc(-n4c5ccccc5c5cc6oc7ccccc7c6cc54)c(-c4nc(-c5ccccc5)nc(-c5ccccc5)n4)c3)c2)cc1]

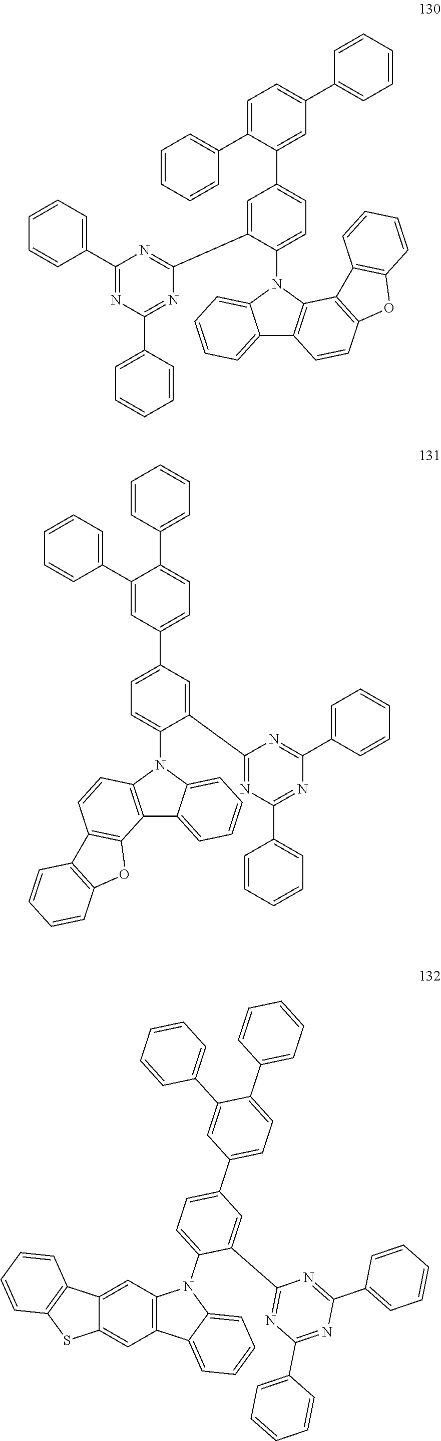 [SMILES: c1ccc(-c2ccc(-c3ccccc3)c(-c3ccc(-n4c5ccccc5c5ccc6oc7ccccc7c6c54)c(-c4nc(-c5ccccc5)nc(-c5ccccc5)n4)c3)c2)cc1 ; c1ccc(-c2nc(-c3ccccc3)nc(-c3cc(-c4ccc(-c5ccccc5)c(-c5ccccc5)c4)ccc3-n3c4ccccc4c4c5oc6ccccc6c5ccc43)n2)cc1 ; c1ccc(-c2nc(-c3ccccc3)nc(-c3cc(-c4ccc(-c5ccccc5)c(-c5ccccc5)c4)ccc3-n3c4ccccc4c4cc5sc6ccccc6c5cc43)n2)cc1]

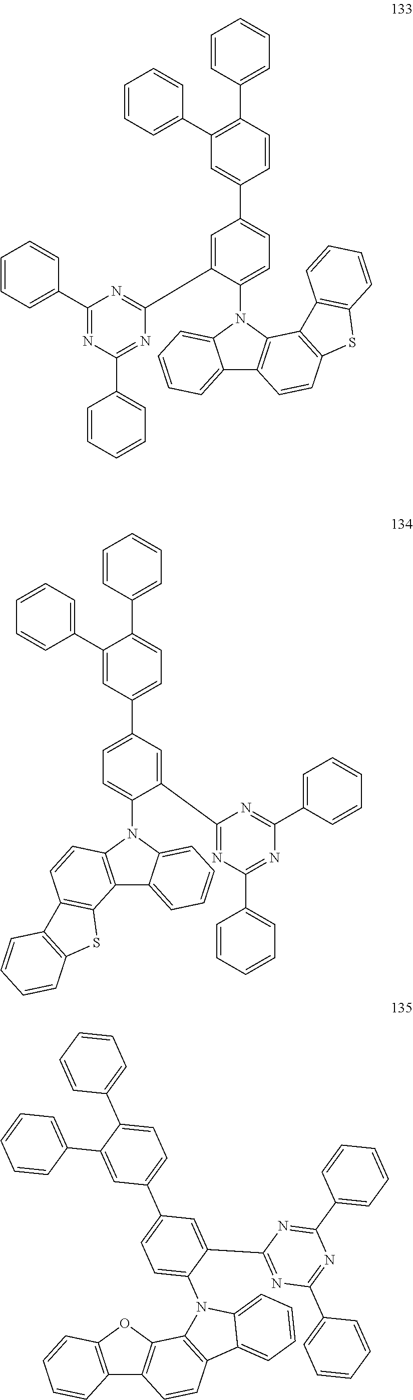 [SMILES: c1ccc(-c2nc(-c3ccccc3)nc(-c3cc(-c4ccc(-c5ccccc5)c(-c5ccccc5)c4)ccc3-n3c4ccccc4c4ccc5sc6ccccc6c5c43)n2)cc1 ; c1ccc(-c2nc(-c3ccccc3)nc(-c3cc(-c4ccc(-c5ccccc5)c(-c5ccccc5)c4)ccc3-n3c4ccccc4c4c5sc6ccccc6c5ccc43)n2)cc1 ; c1ccc(-c2nc(-c3ccccc3)nc(-c3cc(-c4ccc(-c5ccccc5)c(-c5ccccc5)c4)ccc3-n3c4ccccc4c4ccc5c6ccccc6oc5c43)n2)cc1]

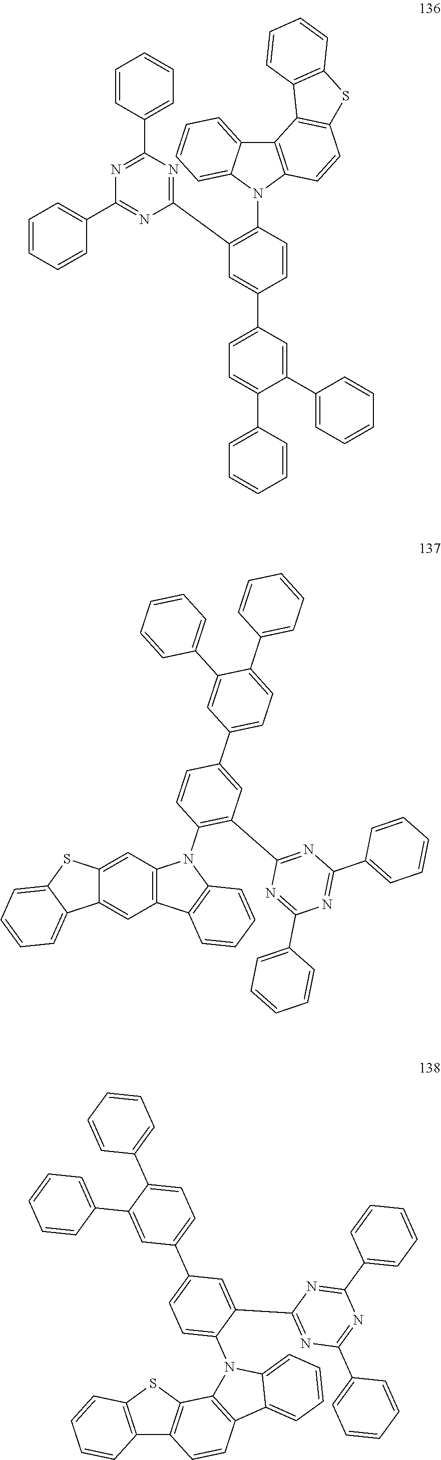 [SMILES: c1ccc(-c2nc(-c3ccccc3)nc(-c3cc(-c4ccc(-c5ccccc5)c(-c5ccccc5)c4)ccc3-n3c4ccccc4c4c5c(ccc43)sc3ccccc35)n2)cc1 ; c1ccc(-c2nc(-c3ccccc3)nc(-c3cc(-c4ccc(-c5ccccc5)c(-c5ccccc5)c4)ccc3-n3c4ccccc4c4cc5c(cc43)sc3ccccc35)n2)cc1 ; c1ccc(-c2nc(-c3ccccc3)nc(-c3cc(-c4ccc(-c5ccccc5)c(-c5ccccc5)c4)ccc3-n3c4ccccc4c4ccc5c6ccccc6sc5c43)n2)cc1]

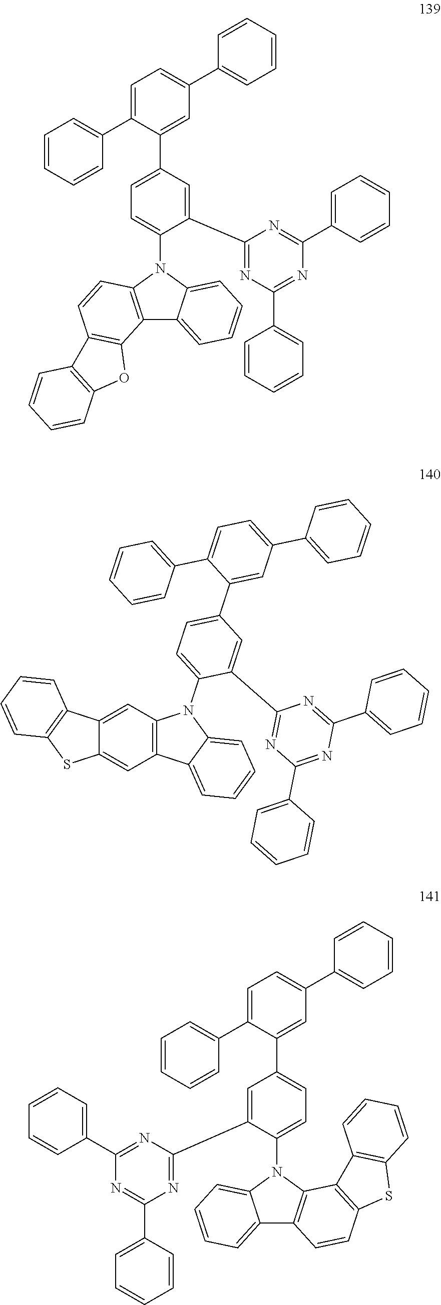 [SMILES: c1ccc(-c2ccc(-c3ccccc3)c(-c3ccc(-n4c5ccccc5c5c6oc7ccccc7c6ccc54)c(-c4nc(-c5ccccc5)nc(-c5ccccc5)n4)c3)c2)cc1 ; c1ccc(-c2ccc(-c3ccccc3)c(-c3ccc(-n4c5ccccc5c5cc6sc7ccccc7c6cc54)c(-c4nc(-c5ccccc5)nc(-c5ccccc5)n4)c3)c2)cc1 ; c1ccc(-c2ccc(-c3ccccc3)c(-c3ccc(-n4c5ccccc5c5ccc6sc7ccccc7c6c54)c(-c4nc(-c5ccccc5)nc(-c5ccccc5)n4)c3)c2)cc1]

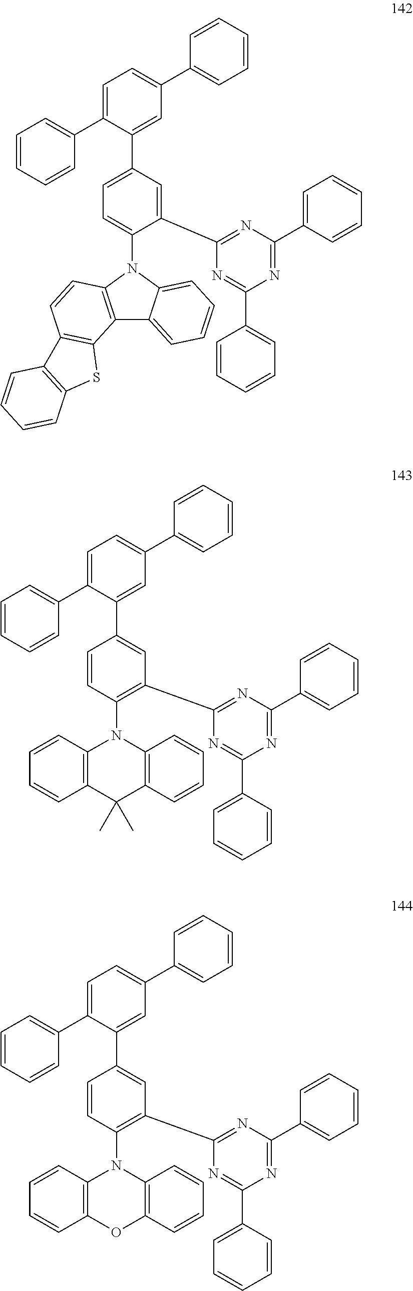 [SMILES: c1ccc(-c2ccc(-c3ccccc3)c(-c3ccc(-n4c5ccccc5c5c6sc7ccccc7c6ccc54)c(-c4nc(-c5ccccc5)nc(-c5ccccc5)n4)c3)c2)cc1 ; CC1(C)c2ccccc2N(c2ccc(-c3cc(-c4ccccc4)ccc3-c3ccccc3)cc2-c2nc(-c3ccccc3)nc(-c3ccccc3)n2)c2ccccc21 ; c1ccc(-c2ccc(-c3ccccc3)c(-c3ccc(N4c5ccccc5Oc5ccccc54)c(-c4nc(-c5ccccc5)nc(-c5ccccc5)n4)c3)c2)cc1]

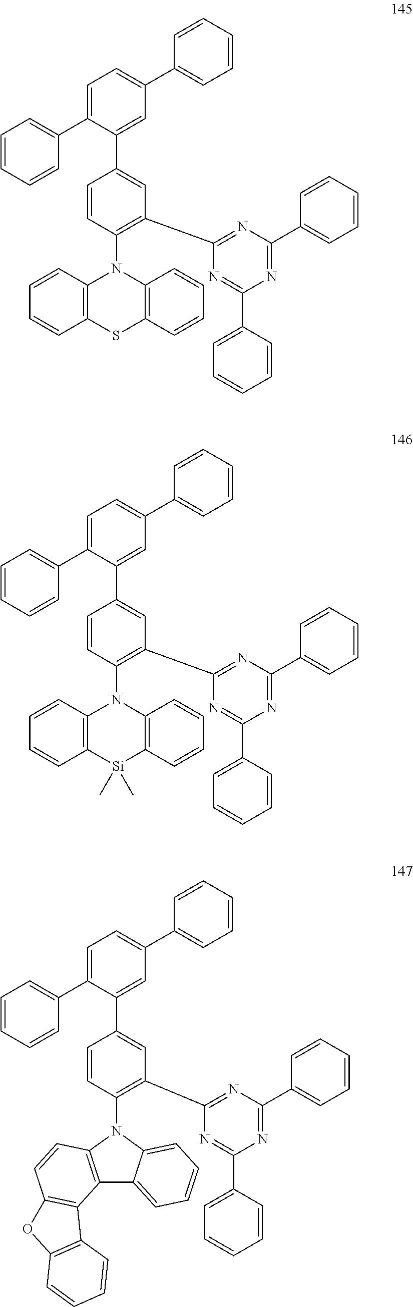 [SMILES: c1ccc(-c2ccc(-c3ccccc3)c(-c3ccc(N4c5ccccc5Sc5ccccc54)c(-c4nc(-c5ccccc5)nc(-c5ccccc5)n4)c3)c2)cc1 ; C[Si]1(C)c2ccccc2N(c2ccc(-c3cc(-c4ccccc4)ccc3-c3ccccc3)cc2-c2nc(-c3ccccc3)nc(-c3ccccc3)n2)c2ccccc21 ; c1ccc(-c2ccc(-c3ccccc3)c(-c3ccc(-n4c5ccccc5c5c6c(ccc54)oc4ccccc46)c(-c4nc(-c5ccccc5)nc(-c5ccccc5)n4)c3)c2)cc1]

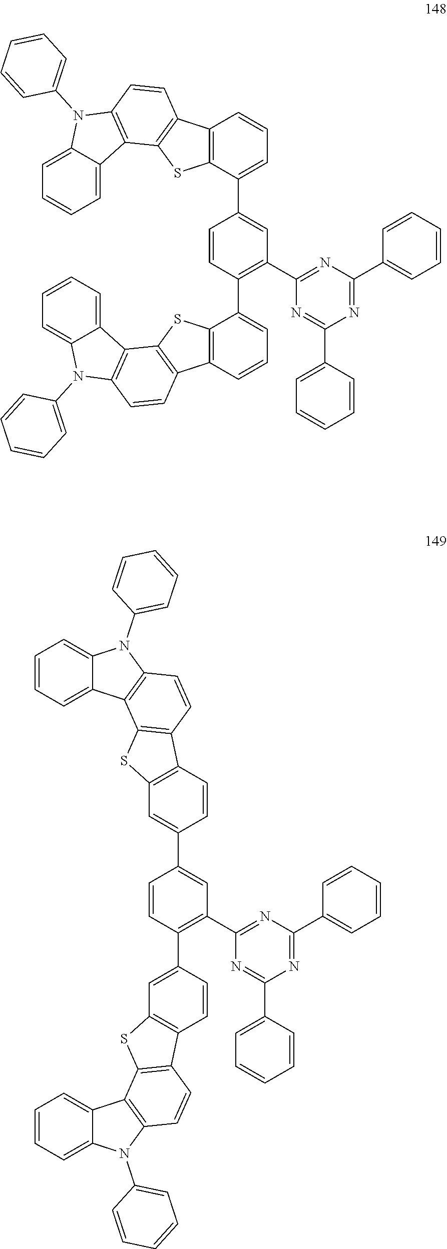 [SMILES: c1ccc(-c2nc(-c3ccccc3)nc(-c3cc(-c4cccc5c4sc4c5ccc5c4c4ccccc4n5-c4ccccc4)ccc3-c3cccc4c3sc3c4ccc4c3c3ccccc3n4-c3ccccc3)n2)cc1 ; c1ccc(-c2nc(-c3ccccc3)nc(-c3cc(-c4ccc5c(c4)sc4c5ccc5c4c4ccccc4n5-c4ccccc4)ccc3-c3ccc4c(c3)sc3c4ccc4c3c3ccccc3n4-c3ccccc3)n2)cc1]

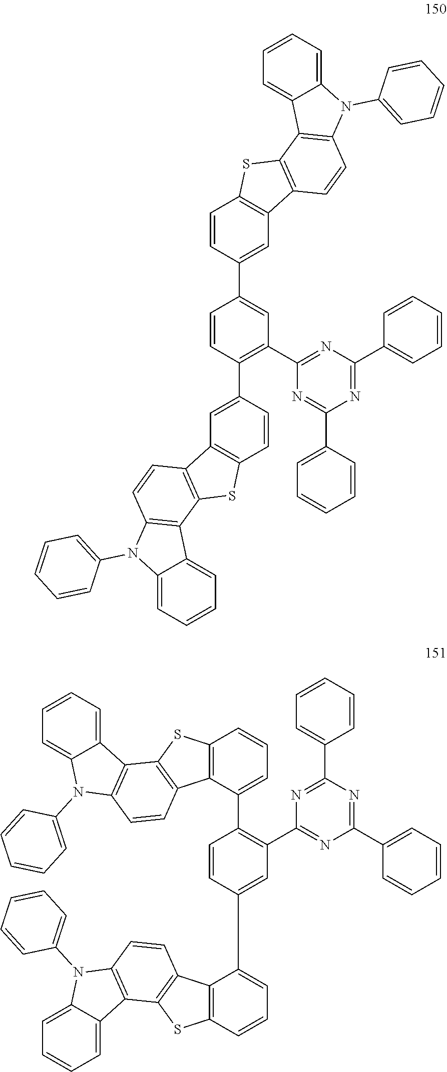 [SMILES: c1ccc(-c2nc(-c3ccccc3)nc(-c3cc(-c4ccc5sc6c(ccc7c6c6ccccc6n7-c6ccccc6)c5c4)ccc3-c3ccc4sc5c(ccc6c5c5ccccc5n6-c5ccccc5)c4c3)n2)cc1 ; c1ccc(-c2nc(-c3ccccc3)nc(-c3cc(-c4cccc5sc6c(ccc7c6c6ccccc6n7-c6ccccc6)c45)ccc3-c3cccc4sc5c(ccc6c5c5ccccc5n6-c5ccccc5)c34)n2)cc1]

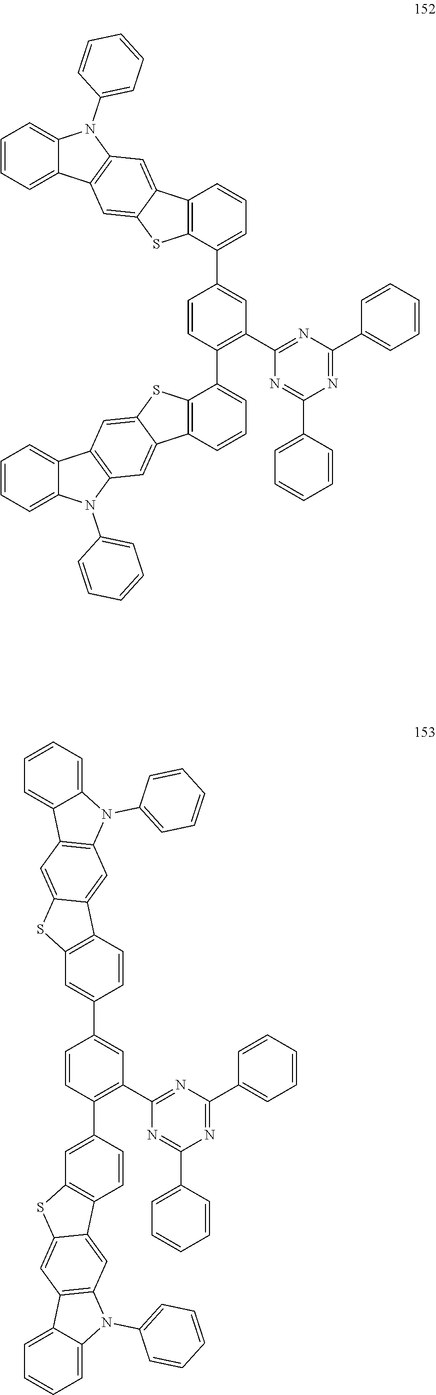 [SMILES: c1ccc(-c2nc(-c3ccccc3)nc(-c3cc(-c4cccc5c4sc4cc6c7ccccc7n(-c7ccccc7)c6cc45)ccc3-c3cccc4c3sc3cc5c6ccccc6n(-c6ccccc6)c5cc34)n2)cc1 ; c1ccc(-c2nc(-c3ccccc3)nc(-c3cc(-c4ccc5c(c4)sc4cc6c7ccccc7n(-c7ccccc7)c6cc45)ccc3-c3ccc4c(c3)sc3cc5c6ccccc6n(-c6ccccc6)c5cc34)n2)cc1]

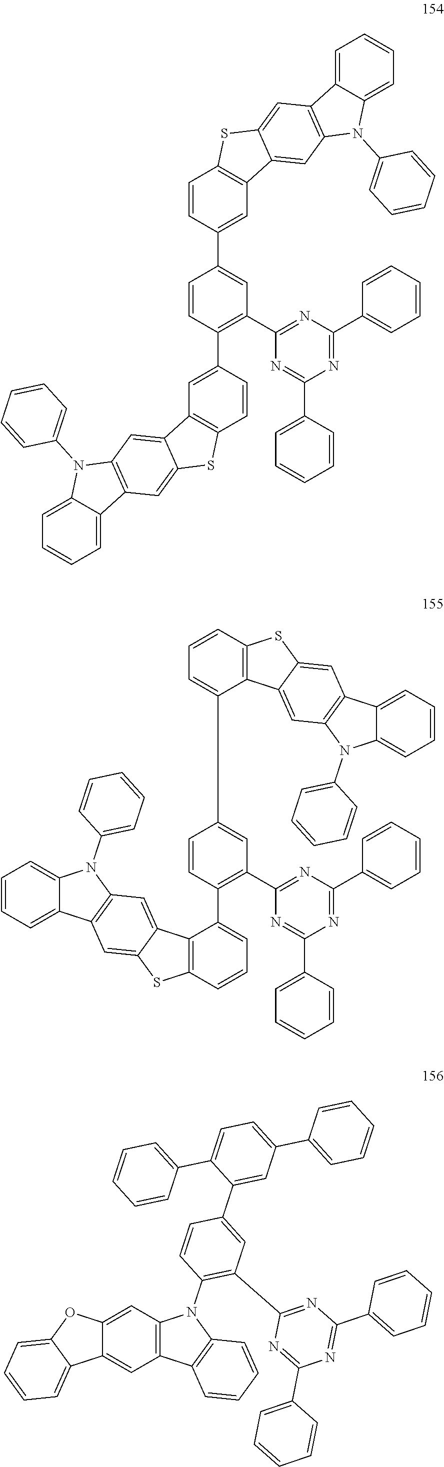 [SMILES: c1ccc(-c2nc(-c3ccccc3)nc(-c3cc(-c4ccc5sc6cc7c8ccccc8n(-c8ccccc8)c7cc6c5c4)ccc3-c3ccc4sc5cc6c7ccccc7n(-c7ccccc7)c6cc5c4c3)n2)cc1 ; c1ccc(-c2nc(-c3ccccc3)nc(-c3cc(-c4cccc5sc6cc7c8ccccc8n(-c8ccccc8)c7cc6c45)ccc3-c3cccc4sc5cc6c7ccccc7n(-c7ccccc7)c6cc5c34)n2)cc1 ; c1ccc(-c2ccc(-c3ccccc3)c(-c3ccc(-n4c5ccccc5c5cc6c(cc54)oc4ccccc46)c(-c4nc(-c5ccccc5)nc(-c5ccccc5)n4)c3)c2)cc1]

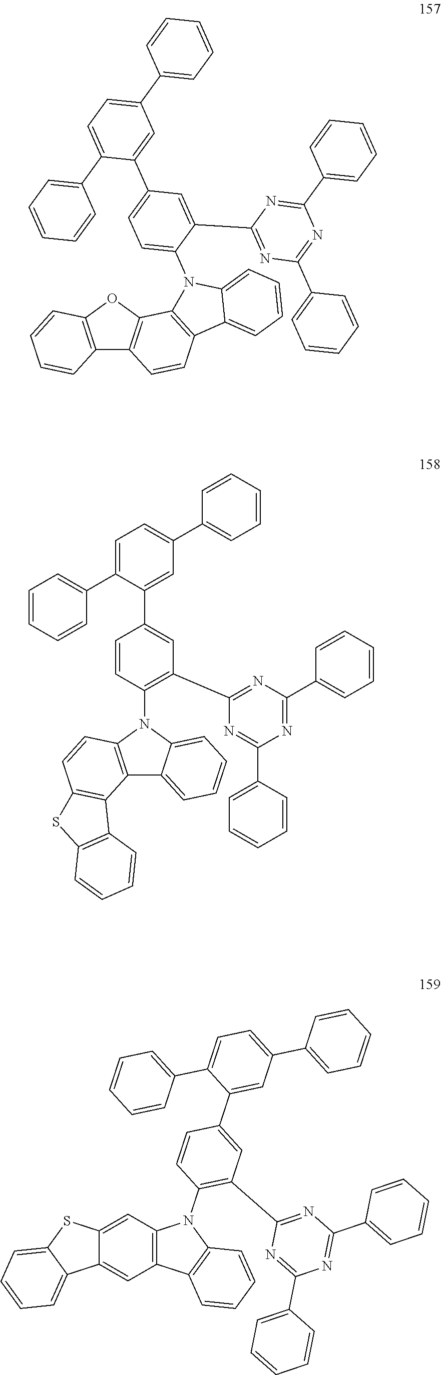 [SMILES: c1ccc(-c2ccc(-c3ccccc3)c(-c3ccc(-n4c5ccccc5c5ccc6c7ccccc7oc6c54)c(-c4nc(-c5ccccc5)nc(-c5ccccc5)n4)c3)c2)cc1 ; c1ccc(-c2ccc(-c3ccccc3)c(-c3ccc(-n4c5ccccc5c5c6c(ccc54)sc4ccccc46)c(-c4nc(-c5ccccc5)nc(-c5ccccc5)n4)c3)c2)cc1 ; c1ccc(-c2ccc(-c3ccccc3)c(-c3ccc(-n4c5ccccc5c5cc6c(cc54)sc4ccccc46)c(-c4nc(-c5ccccc5)nc(-c5ccccc5)n4)c3)c2)cc1]

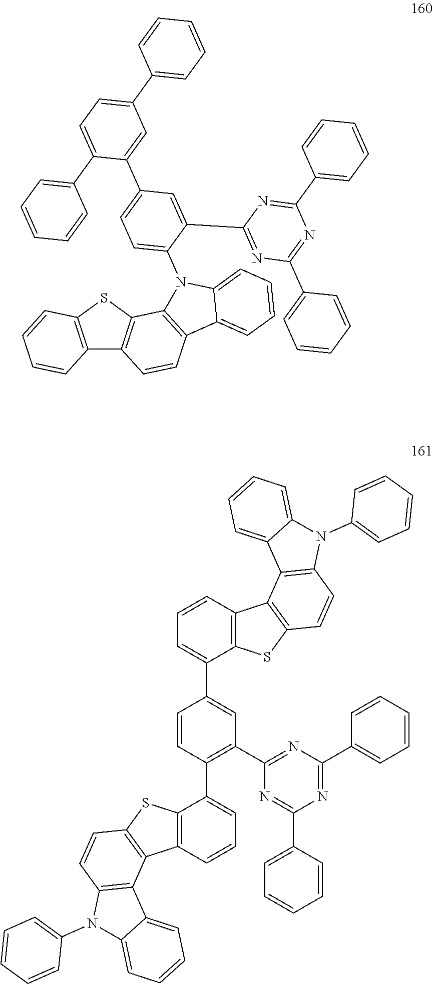 [SMILES: c1ccc(-c2ccc(-c3ccccc3)c(-c3ccc(-n4c5ccccc5c5ccc6c7ccccc7sc6c54)c(-c4nc(-c5ccccc5)nc(-c5ccccc5)n4)c3)c2)cc1 ; c1ccc(-c2nc(-c3ccccc3)nc(-c3cc(-c4cccc5c4sc4ccc6c(c7ccccc7n6-c6ccccc6)c45)ccc3-c3cccc4c3sc3ccc5c(c6ccccc6n5-c5ccccc5)c34)n2)cc1]

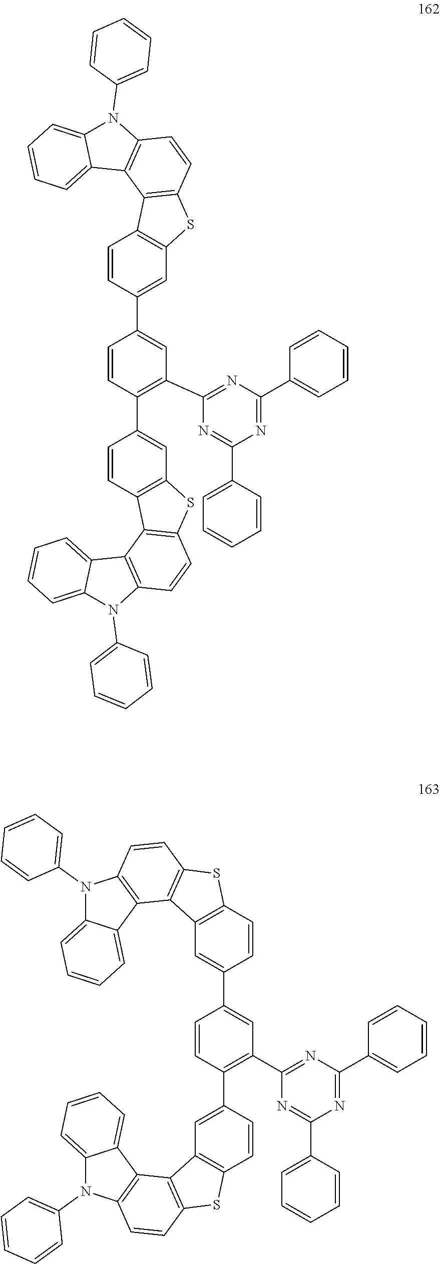 [SMILES: c1ccc(-c2nc(-c3ccccc3)nc(-c3cc(-c4ccc5c(c4)sc4ccc6c(c7ccccc7n6-c6ccccc6)c45)ccc3-c3ccc4c(c3)sc3ccc5c(c6ccccc6n5-c5ccccc5)c34)n2)cc1 ; c1ccc(-c2nc(-c3ccccc3)nc(-c3cc(-c4ccc5sc6ccc7c(c8ccccc8n7-c7ccccc7)c6c5c4)ccc3-c3ccc4sc5ccc6c(c7ccccc7n6-c6ccccc6)c5c4c3)n2)cc1]

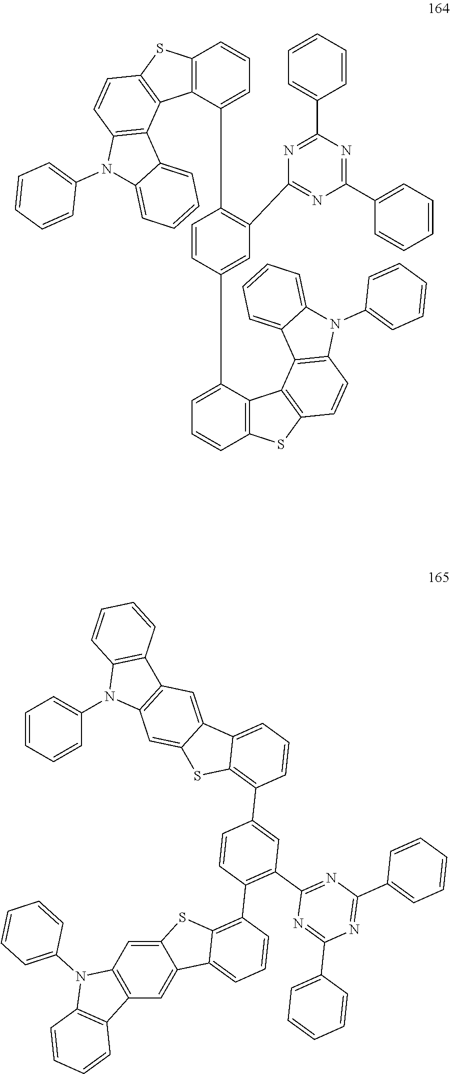 [SMILES: c1ccc(-c2nc(-c3ccccc3)nc(-c3cc(-c4cccc5sc6ccc7c(c8ccccc8n7-c7ccccc7)c6c45)ccc3-c3cccc4sc5ccc6c(c7ccccc7n6-c6ccccc6)c5c34)n2)cc1 ; c1ccc(-c2nc(-c3ccccc3)nc(-c3cc(-c4cccc5c4sc4cc6c(cc45)c4ccccc4n6-c4ccccc4)ccc3-c3cccc4c3sc3cc5c(cc34)c3ccccc3n5-c3ccccc3)n2)cc1]

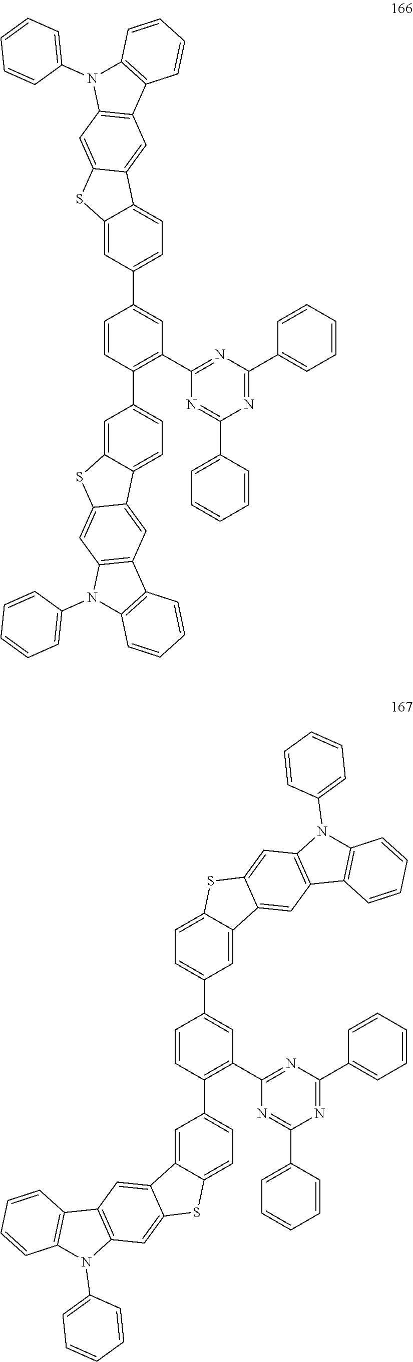 [SMILES: c1ccc(-c2nc(-c3ccccc3)nc(-c3cc(-c4ccc5c(c4)sc4cc6c(cc45)c4ccccc4n6-c4ccccc4)ccc3-c3ccc4c(c3)sc3cc5c(cc34)c3ccccc3n5-c3ccccc3)n2)cc1 ; c1ccc(-c2nc(-c3ccccc3)nc(-c3cc(-c4ccc5sc6cc7c(cc6c5c4)c4ccccc4n7-c4ccccc4)ccc3-c3ccc4sc5cc6c(cc5c4c3)c3ccccc3n6-c3ccccc3)n2)cc1]

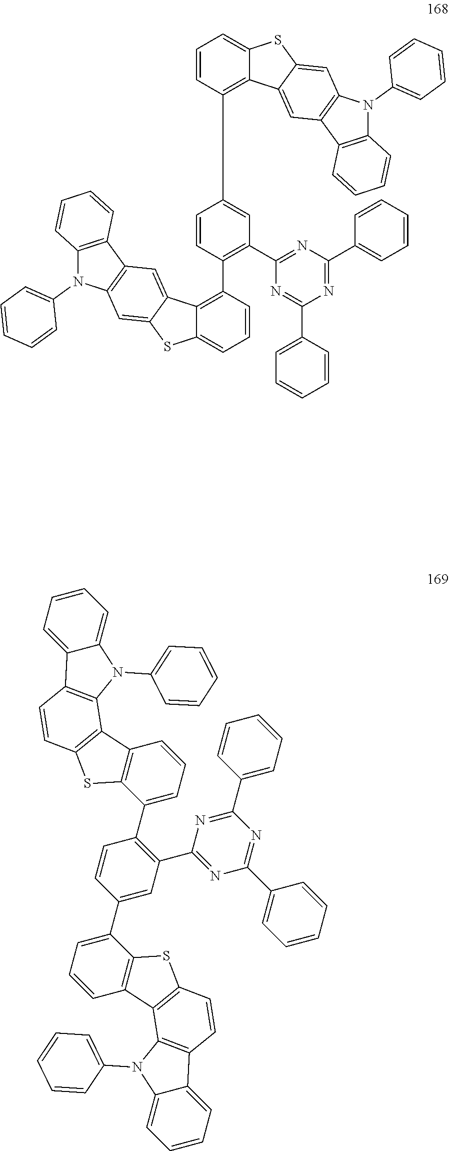 [SMILES: c1ccc(-c2nc(-c3ccccc3)nc(-c3cc(-c4cccc5sc6cc7c(cc6c45)c4ccccc4n7-c4ccccc4)ccc3-c3cccc4sc5cc6c(cc5c34)c3ccccc3n6-c3ccccc3)n2)cc1 ; c1ccc(-c2nc(-c3ccccc3)nc(-c3cc(-c4cccc5c4sc4ccc6c7ccccc7n(-c7ccccc7)c6c45)ccc3-c3cccc4c3sc3ccc5c6ccccc6n(-c6ccccc6)c5c34)n2)cc1]

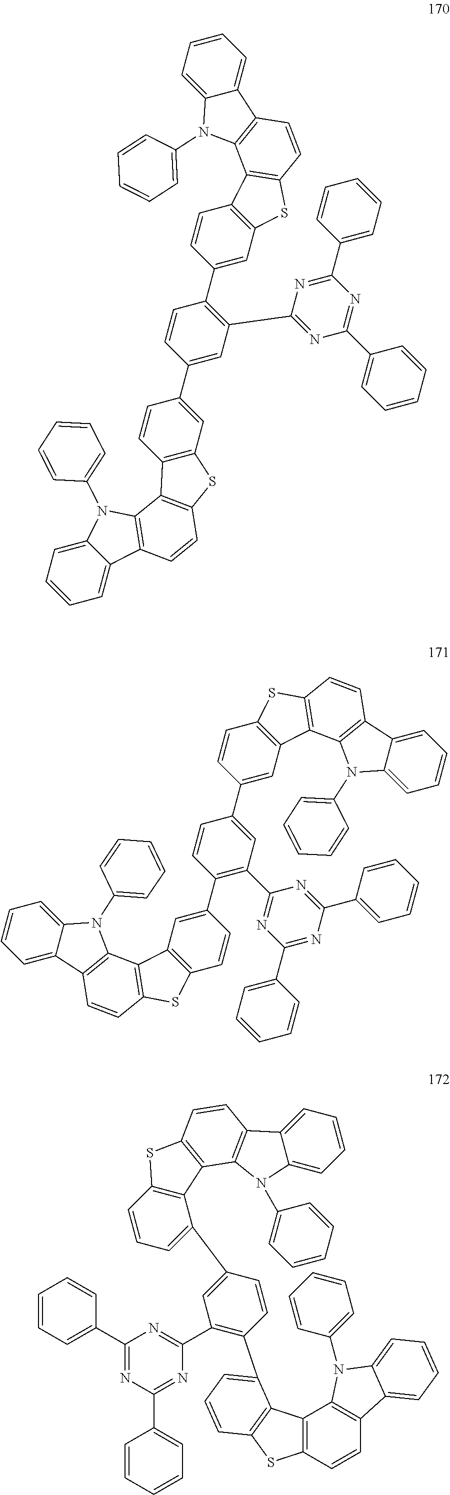 [SMILES: c1ccc(-c2nc(-c3ccccc3)nc(-c3cc(-c4ccc5c(c4)sc4ccc6c7ccccc7n(-c7ccccc7)c6c45)ccc3-c3ccc4c(c3)sc3ccc5c6ccccc6n(-c6ccccc6)c5c34)n2)cc1 ; c1ccc(-c2nc(-c3ccccc3)nc(-c3cc(-c4ccc5sc6ccc7c8ccccc8n(-c8ccccc8)c7c6c5c4)ccc3-c3ccc4sc5ccc6c7ccccc7n(-c7ccccc7)c6c5c4c3)n2)cc1 ; c1ccc(-c2nc(-c3ccccc3)nc(-c3cc(-c4cccc5sc6ccc7c8ccccc8n(-c8ccccc8)c7c6c45)ccc3-c3cccc4sc5ccc6c7ccccc7n(-c7ccccc7)c6c5c34)n2)cc1]

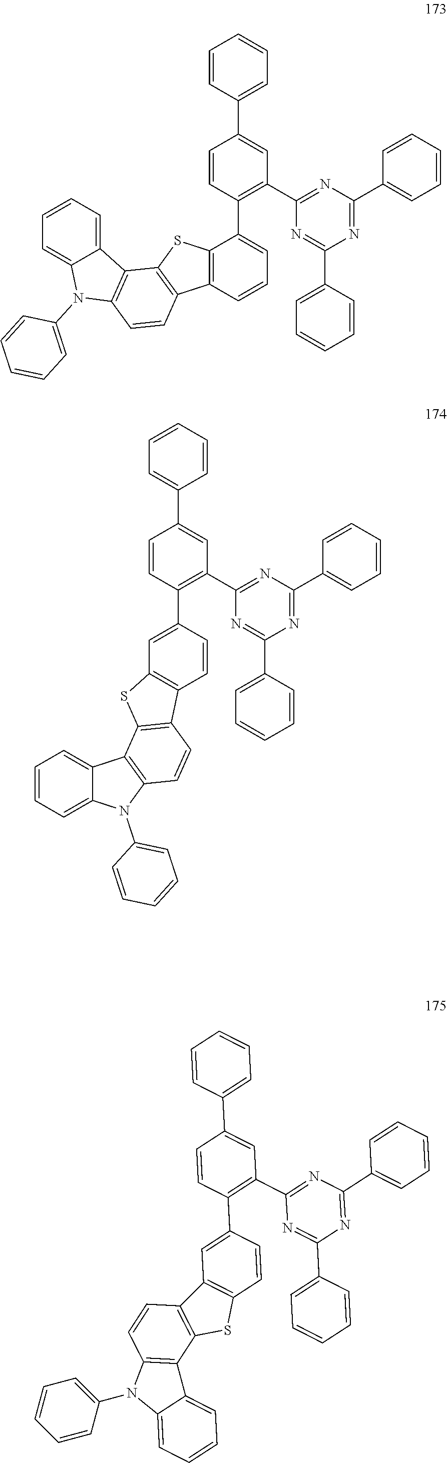 [SMILES: c1ccc(-c2ccc(-c3cccc4c3sc3c4ccc4c3c3ccccc3n4-c3ccccc3)c(-c3nc(-c4ccccc4)nc(-c4ccccc4)n3)c2)cc1 ; c1ccc(-c2ccc(-c3ccc4c(c3)sc3c4ccc4c3c3ccccc3n4-c3ccccc3)c(-c3nc(-c4ccccc4)nc(-c4ccccc4)n3)c2)cc1 ; c1ccc(-c2ccc(-c3ccc4sc5c(ccc6c5c5ccccc5n6-c5ccccc5)c4c3)c(-c3nc(-c4ccccc4)nc(-c4ccccc4)n3)c2)cc1]

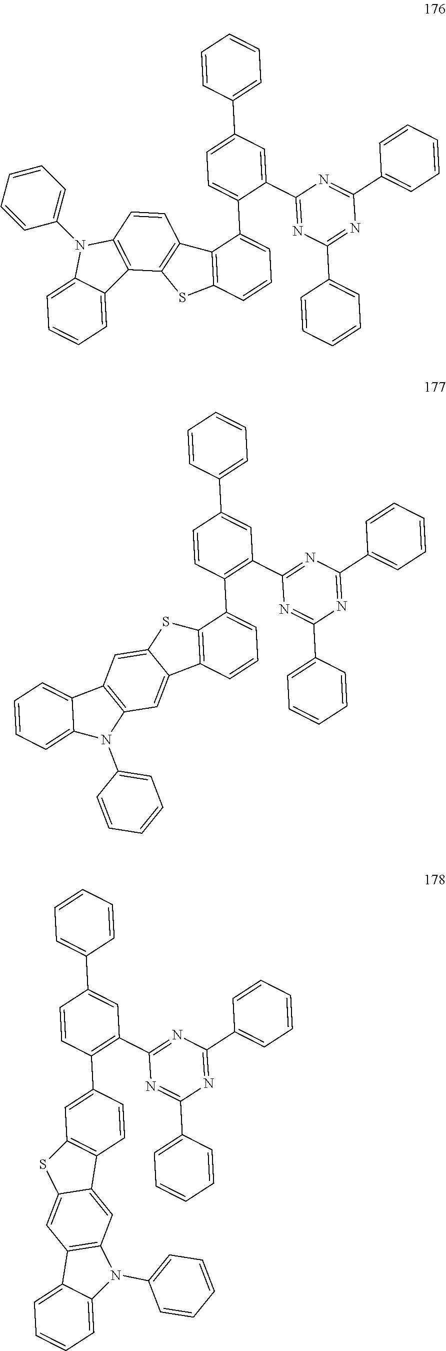 [SMILES: c1ccc(-c2ccc(-c3cccc4sc5c(ccc6c5c5ccccc5n6-c5ccccc5)c34)c(-c3nc(-c4ccccc4)nc(-c4ccccc4)n3)c2)cc1 ; c1ccc(-c2ccc(-c3cccc4c3sc3cc5c6ccccc6n(-c6ccccc6)c5cc34)c(-c3nc(-c4ccccc4)nc(-c4ccccc4)n3)c2)cc1 ; c1ccc(-c2ccc(-c3ccc4c(c3)sc3cc5c6ccccc6n(-c6ccccc6)c5cc34)c(-c3nc(-c4ccccc4)nc(-c4ccccc4)n3)c2)cc1]

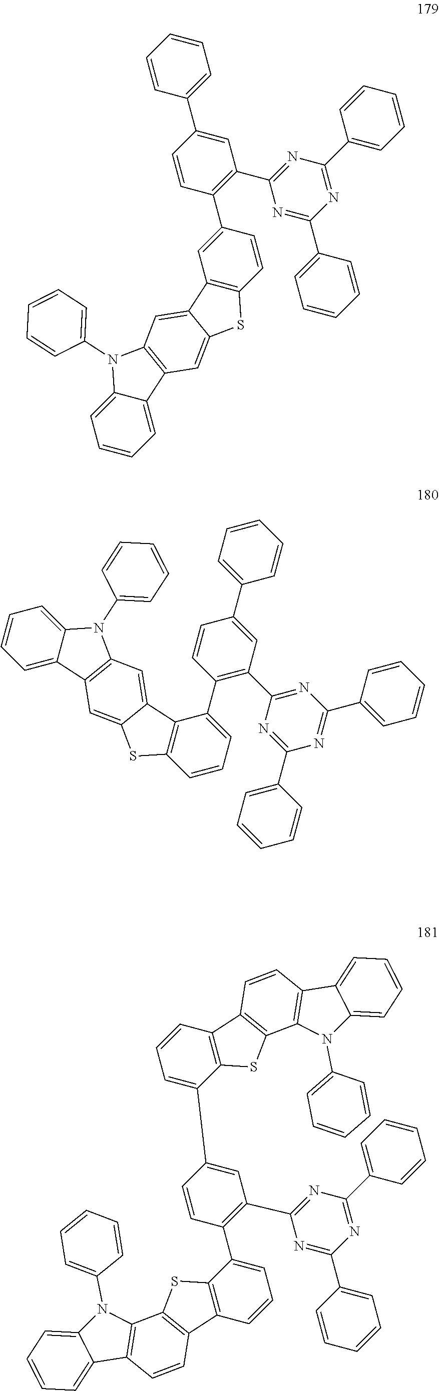 [SMILES: c1ccc(-c2ccc(-c3ccc4sc5cc6c7ccccc7n(-c7ccccc7)c6cc5c4c3)c(-c3nc(-c4ccccc4)nc(-c4ccccc4)n3)c2)cc1 ; c1ccc(-c2ccc(-c3cccc4sc5cc6c7ccccc7n(-c7ccccc7)c6cc5c34)c(-c3nc(-c4ccccc4)nc(-c4ccccc4)n3)c2)cc1 ; c1ccc(-c2nc(-c3ccccc3)nc(-c3cc(-c4cccc5c4sc4c5ccc5c6ccccc6n(-c6ccccc6)c54)ccc3-c3cccc4c3sc3c4ccc4c5ccccc5n(-c5ccccc5)c43)n2)cc1]

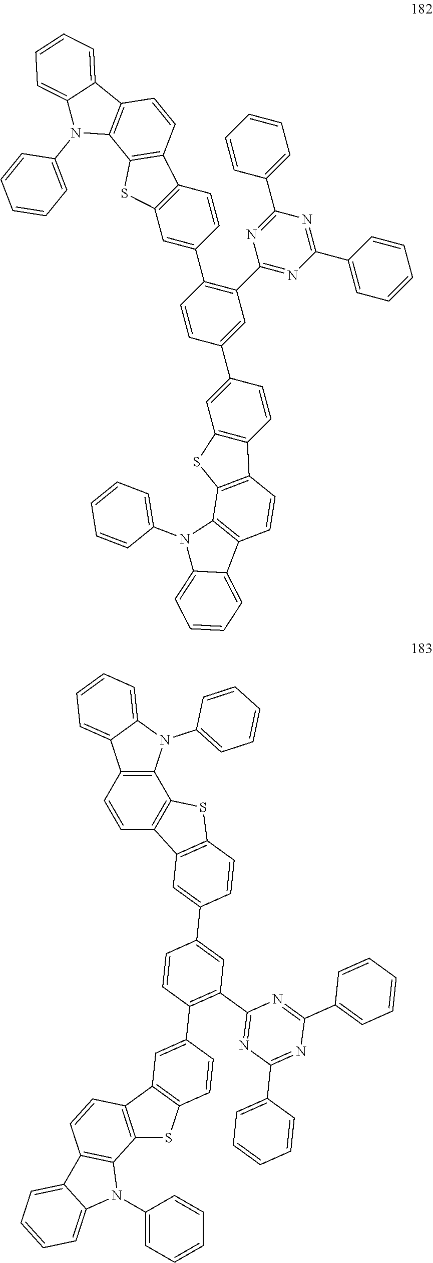 [SMILES: c1ccc(-c2nc(-c3ccccc3)nc(-c3cc(-c4ccc5c(c4)sc4c5ccc5c6ccccc6n(-c6ccccc6)c54)ccc3-c3ccc4c(c3)sc3c4ccc4c5ccccc5n(-c5ccccc5)c43)n2)cc1 ; c1ccc(-c2nc(-c3ccccc3)nc(-c3cc(-c4ccc5sc6c(ccc7c8ccccc8n(-c8ccccc8)c76)c5c4)ccc3-c3ccc4sc5c(ccc6c7ccccc7n(-c7ccccc7)c65)c4c3)n2)cc1]

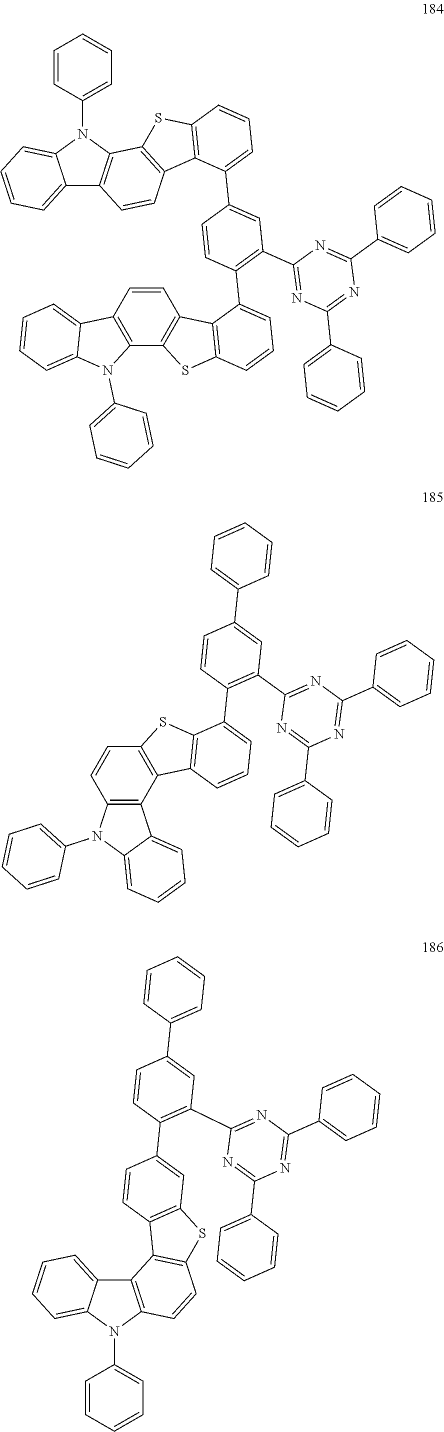 [SMILES: c1ccc(-c2nc(-c3ccccc3)nc(-c3cc(-c4cccc5sc6c(ccc7c8ccccc8n(-c8ccccc8)c76)c45)ccc3-c3cccc4sc5c(ccc6c7ccccc7n(-c7ccccc7)c65)c34)n2)cc1 ; c1ccc(-c2ccc(-c3cccc4c3sc3ccc5c(c6ccccc6n5-c5ccccc5)c34)c(-c3nc(-c4ccccc4)nc(-c4ccccc4)n3)c2)cc1 ; c1ccc(-c2ccc(-c3ccc4c(c3)sc3ccc5c(c6ccccc6n5-c5ccccc5)c34)c(-c3nc(-c4ccccc4)nc(-c4ccccc4)n3)c2)cc1]

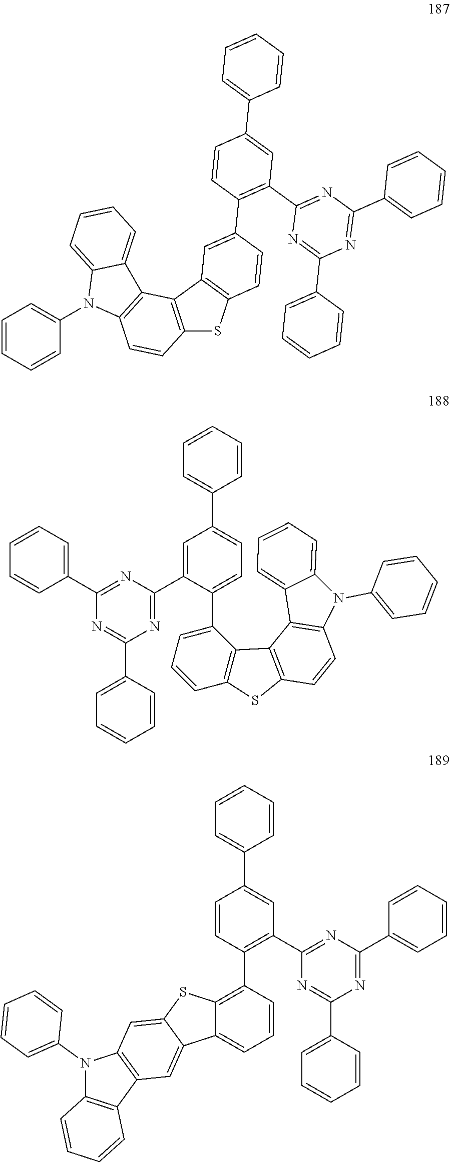 [SMILES: c1ccc(-c2ccc(-c3ccc4sc5ccc6c(c7ccccc7n6-c6ccccc6)c5c4c3)c(-c3nc(-c4ccccc4)nc(-c4ccccc4)n3)c2)cc1 ; c1ccc(-c2ccc(-c3cccc4sc5ccc6c(c7ccccc7n6-c6ccccc6)c5c34)c(-c3nc(-c4ccccc4)nc(-c4ccccc4)n3)c2)cc1 ; c1ccc(-c2ccc(-c3cccc4c3sc3cc5c(cc34)c3ccccc3n5-c3ccccc3)c(-c3nc(-c4ccccc4)nc(-c4ccccc4)n3)c2)cc1]

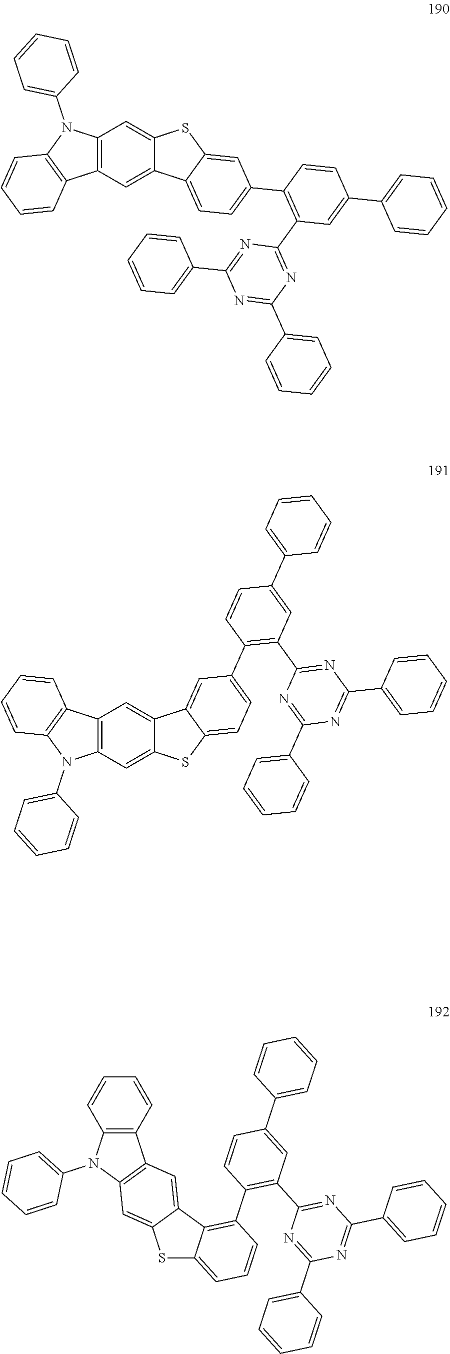 [SMILES: c1ccc(-c2ccc(-c3ccc4c(c3)sc3cc5c(cc34)c3ccccc3n5-c3ccccc3)c(-c3nc(-c4ccccc4)nc(-c4ccccc4)n3)c2)cc1 ; c1ccc(-c2ccc(-c3ccc4sc5cc6c(cc5c4c3)c3ccccc3n6-c3ccccc3)c(-c3nc(-c4ccccc4)nc(-c4ccccc4)n3)c2)cc1 ; c1ccc(-c2ccc(-c3cccc4sc5cc6c(cc5c34)c3ccccc3n6-c3ccccc3)c(-c3nc(-c4ccccc4)nc(-c4ccccc4)n3)c2)cc1]

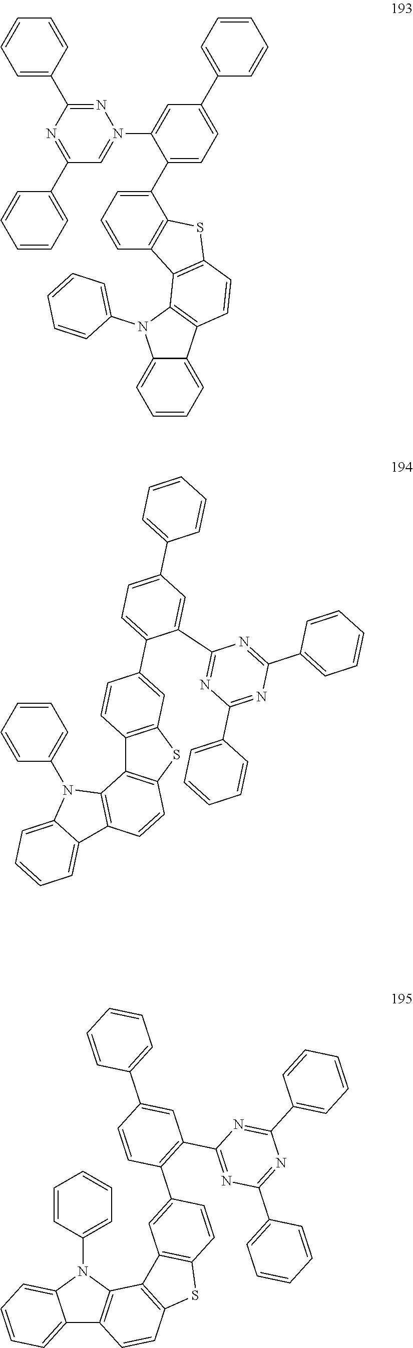

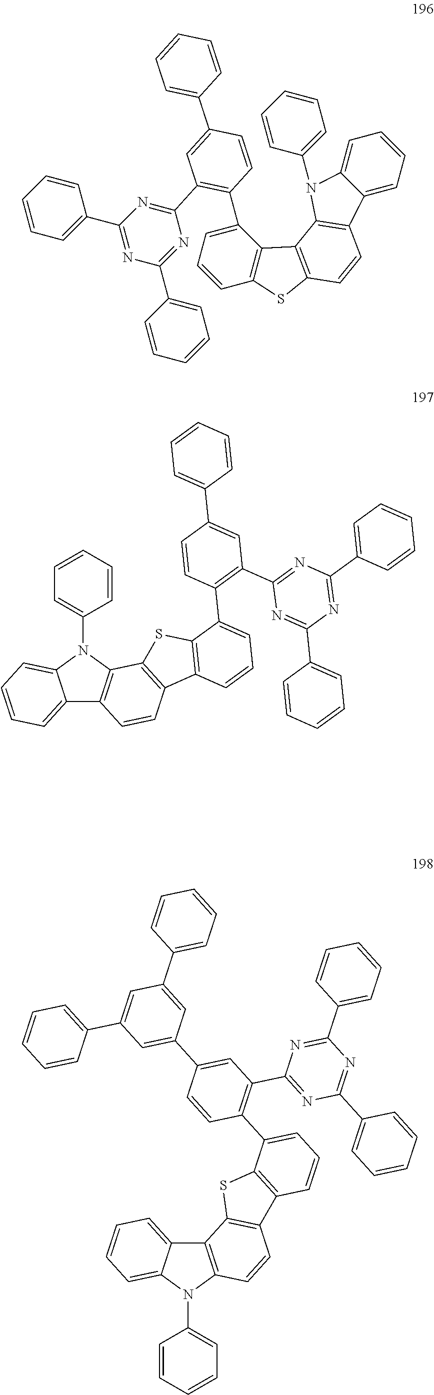 [SMILES: c1ccc(-c2ccc(-c3cccc4sc5ccc6c7ccccc7n(-c7ccccc7)c6c5c34)c(-c3nc(-c4ccccc4)nc(-c4ccccc4)n3)c2)cc1 ; c1ccc(-c2ccc(-c3cccc4c3sc3c4ccc4c5ccccc5n(-c5ccccc5)c43)c(-c3nc(-c4ccccc4)nc(-c4ccccc4)n3)c2)cc1 ; c1ccc(-c2cc(-c3ccccc3)cc(-c3ccc(-c4cccc5c4sc4c5ccc5c4c4ccccc4n5-c4ccccc4)c(-c4nc(-c5ccccc5)nc(-c5ccccc5)n4)c3)c2)cc1]

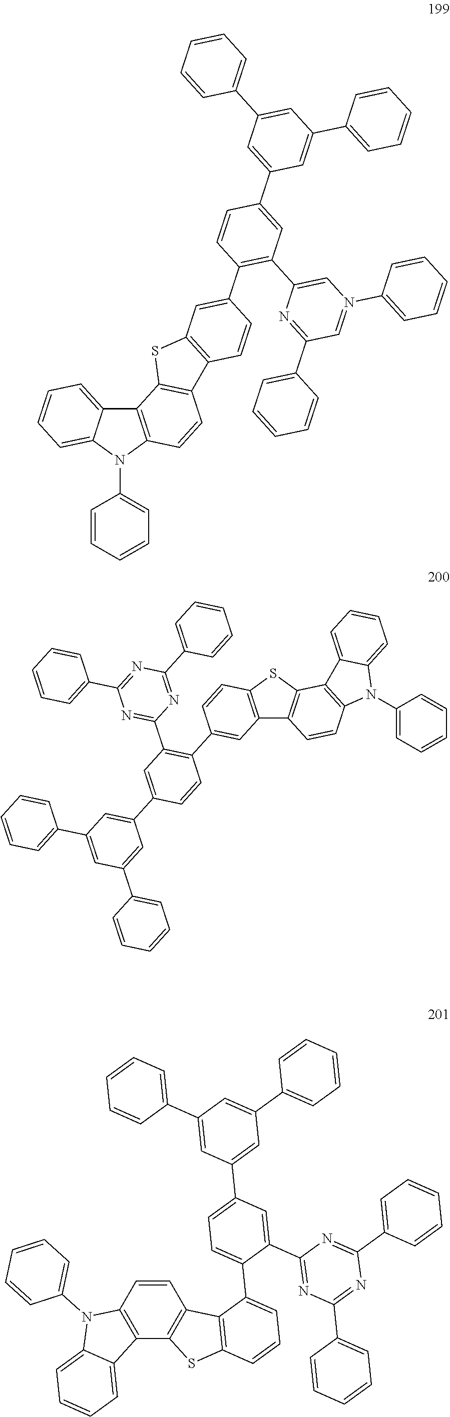

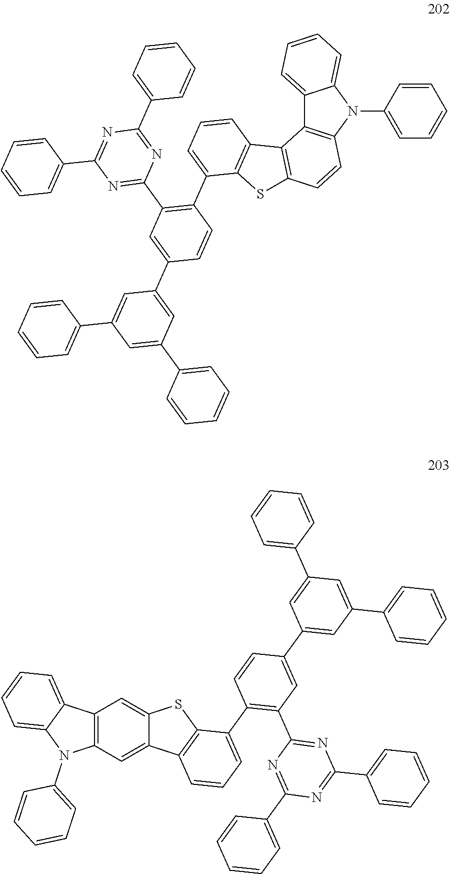 [SMILES: c1ccc(-c2cc(-c3ccccc3)cc(-c3ccc(-c4cccc5c4sc4ccc6c(c7ccccc7n6-c6ccccc6)c45)c(-c4nc(-c5ccccc5)nc(-c5ccccc5)n4)c3)c2)cc1 ; c1ccc(-c2cc(-c3ccccc3)cc(-c3ccc(-c4cccc5c4sc4cc6c7ccccc7n(-c7ccccc7)c6cc45)c(-c4nc(-c5ccccc5)nc(-c5ccccc5)n4)c3)c2)cc1]

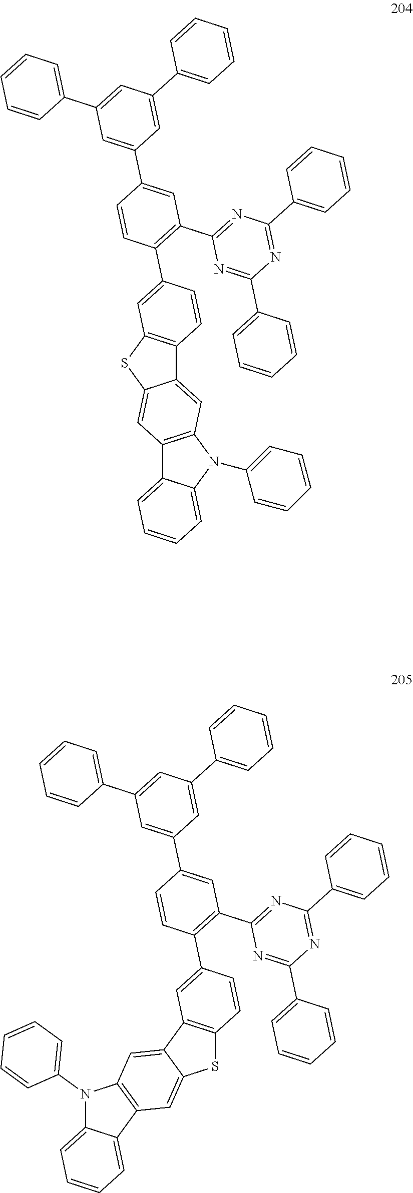 [SMILES: c1ccc(-c2cc(-c3ccccc3)cc(-c3ccc(-c4ccc5c(c4)sc4cc6c7ccccc7n(-c7ccccc7)c6cc45)c(-c4nc(-c5ccccc5)nc(-c5ccccc5)n4)c3)c2)cc1 ; c1ccc(-c2cc(-c3ccccc3)cc(-c3ccc(-c4ccc5sc6cc7c8ccccc8n(-c8ccccc8)c7cc6c5c4)c(-c4nc(-c5ccccc5)nc(-c5ccccc5)n4)c3)c2)cc1]

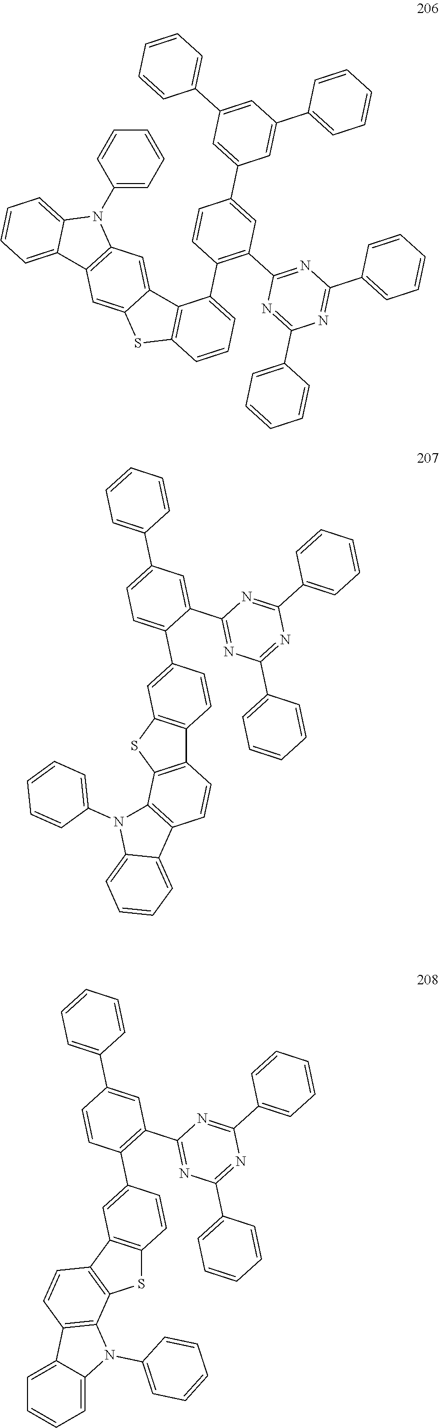 [SMILES: c1ccc(-c2cc(-c3ccccc3)cc(-c3ccc(-c4cccc5sc6cc7c8ccccc8n(-c8ccccc8)c7cc6c45)c(-c4nc(-c5ccccc5)nc(-c5ccccc5)n4)c3)c2)cc1 ; c1ccc(-c2ccc(-c3ccc4c(c3)sc3c4ccc4c5ccccc5n(-c5ccccc5)c43)c(-c3nc(-c4ccccc4)nc(-c4ccccc4)n3)c2)cc1 ; c1ccc(-c2ccc(-c3ccc4sc5c(ccc6c7ccccc7n(-c7ccccc7)c65)c4c3)c(-c3nc(-c4ccccc4)nc(-c4ccccc4)n3)c2)cc1]

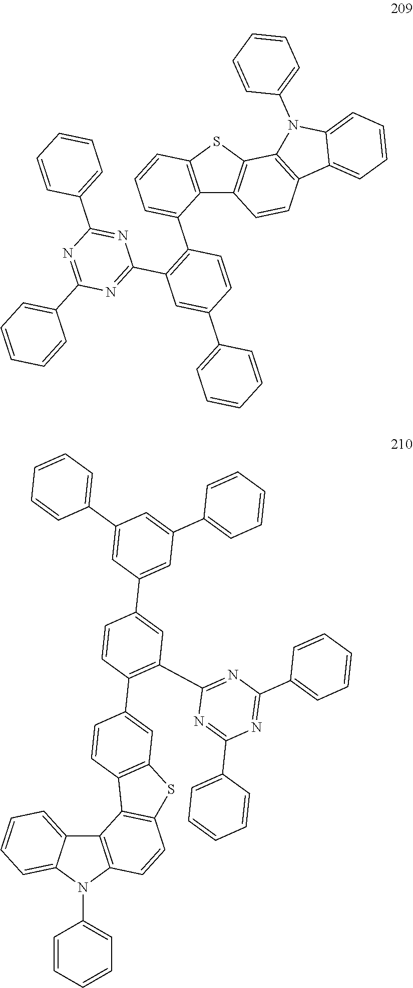 [SMILES: c1ccc(-c2ccc(-c3cccc4sc5c(ccc6c7ccccc7n(-c7ccccc7)c65)c34)c(-c3nc(-c4ccccc4)nc(-c4ccccc4)n3)c2)cc1 ; c1ccc(-c2cc(-c3ccccc3)cc(-c3ccc(-c4ccc5c(c4)sc4ccc6c(c7ccccc7n6-c6ccccc6)c45)c(-c4nc(-c5ccccc5)nc(-c5ccccc5)n4)c3)c2)cc1]

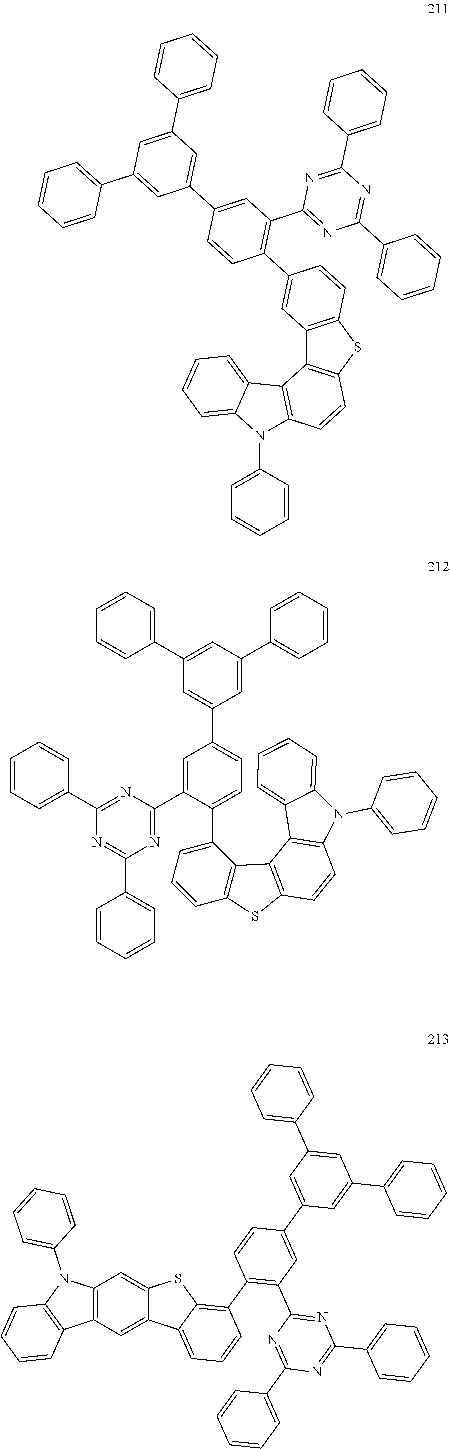 [SMILES: c1ccc(-c2cc(-c3ccccc3)cc(-c3ccc(-c4ccc5sc6ccc7c(c8ccccc8n7-c7ccccc7)c6c5c4)c(-c4nc(-c5ccccc5)nc(-c5ccccc5)n4)c3)c2)cc1 ; c1ccc(-c2cc(-c3ccccc3)cc(-c3ccc(-c4cccc5sc6ccc7c(c8ccccc8n7-c7ccccc7)c6c45)c(-c4nc(-c5ccccc5)nc(-c5ccccc5)n4)c3)c2)cc1 ; c1ccc(-c2cc(-c3ccccc3)cc(-c3ccc(-c4cccc5c4sc4cc6c(cc45)c4ccccc4n6-c4ccccc4)c(-c4nc(-c5ccccc5)nc(-c5ccccc5)n4)c3)c2)cc1]

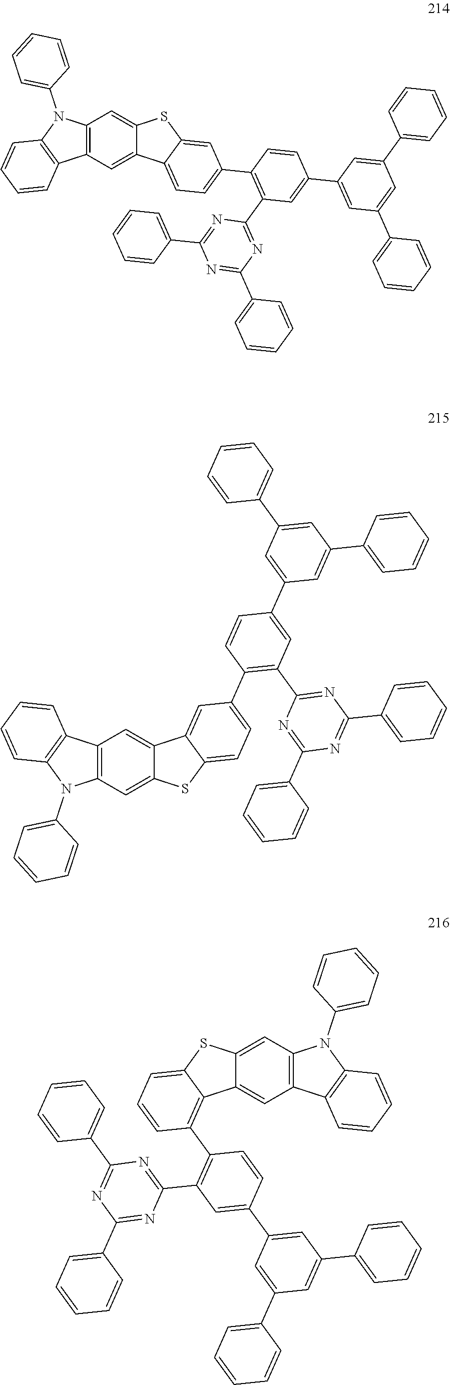 [SMILES: c1ccc(-c2cc(-c3ccccc3)cc(-c3ccc(-c4ccc5c(c4)sc4cc6c(cc45)c4ccccc4n6-c4ccccc4)c(-c4nc(-c5ccccc5)nc(-c5ccccc5)n4)c3)c2)cc1 ; c1ccc(-c2cc(-c3ccccc3)cc(-c3ccc(-c4ccc5sc6cc7c(cc6c5c4)c4ccccc4n7-c4ccccc4)c(-c4nc(-c5ccccc5)nc(-c5ccccc5)n4)c3)c2)cc1 ; c1ccc(-c2cc(-c3ccccc3)cc(-c3ccc(-c4cccc5sc6cc7c(cc6c45)c4ccccc4n7-c4ccccc4)c(-c4nc(-c5ccccc5)nc(-c5ccccc5)n4)c3)c2)cc1]

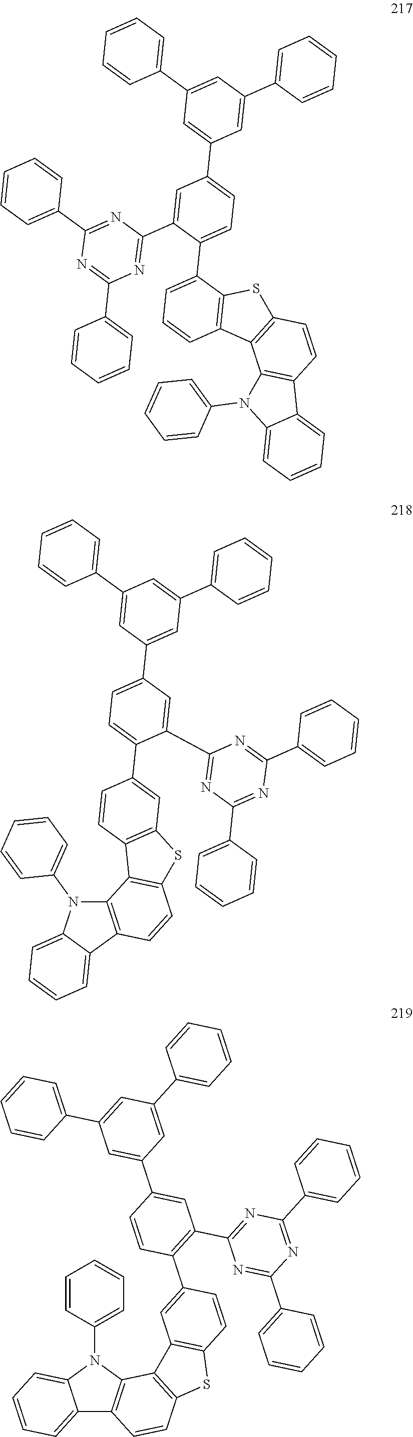 [SMILES: c1ccc(-c2cc(-c3ccccc3)cc(-c3ccc(-c4cccc5c4sc4ccc6c7ccccc7n(-c7ccccc7)c6c45)c(-c4nc(-c5ccccc5)nc(-c5ccccc5)n4)c3)c2)cc1 ; c1ccc(-c2cc(-c3ccccc3)cc(-c3ccc(-c4ccc5c(c4)sc4ccc6c7ccccc7n(-c7ccccc7)c6c45)c(-c4nc(-c5ccccc5)nc(-c5ccccc5)n4)c3)c2)cc1 ; c1ccc(-c2cc(-c3ccccc3)cc(-c3ccc(-c4ccc5sc6ccc7c8ccccc8n(-c8ccccc8)c7c6c5c4)c(-c4nc(-c5ccccc5)nc(-c5ccccc5)n4)c3)c2)cc1]

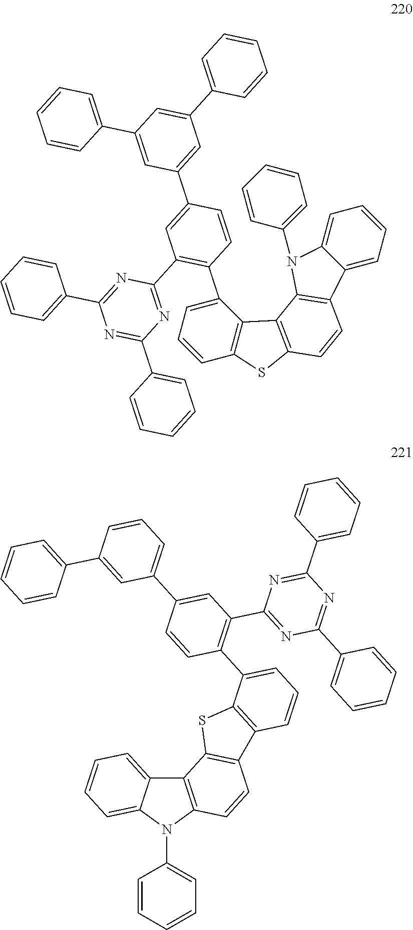 [SMILES: c1ccc(-c2cc(-c3ccccc3)cc(-c3ccc(-c4cccc5sc6ccc7c8ccccc8n(-c8ccccc8)c7c6c45)c(-c4nc(-c5ccccc5)nc(-c5ccccc5)n4)c3)c2)cc1 ; c1ccc(-c2cccc(-c3ccc(-c4cccc5c4sc4c5ccc5c4c4ccccc4n5-c4ccccc4)c(-c4nc(-c5ccccc5)nc(-c5ccccc5)n4)c3)c2)cc1]

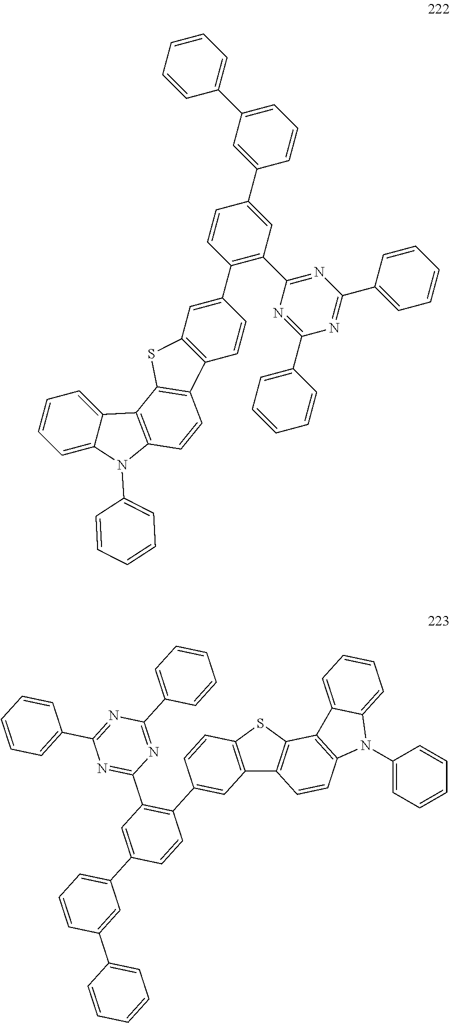 [SMILES: c1ccc(-c2cccc(-c3ccc(-c4ccc5c(c4)sc4c5ccc5c4c4ccccc4n5-c4ccccc4)c(-c4nc(-c5ccccc5)nc(-c5ccccc5)n4)c3)c2)cc1 ; c1ccc(-c2cccc(-c3ccc(-c4ccc5sc6c(ccc7c6c6ccccc6n7-c6ccccc6)c5c4)c(-c4nc(-c5ccccc5)nc(-c5ccccc5)n4)c3)c2)cc1]

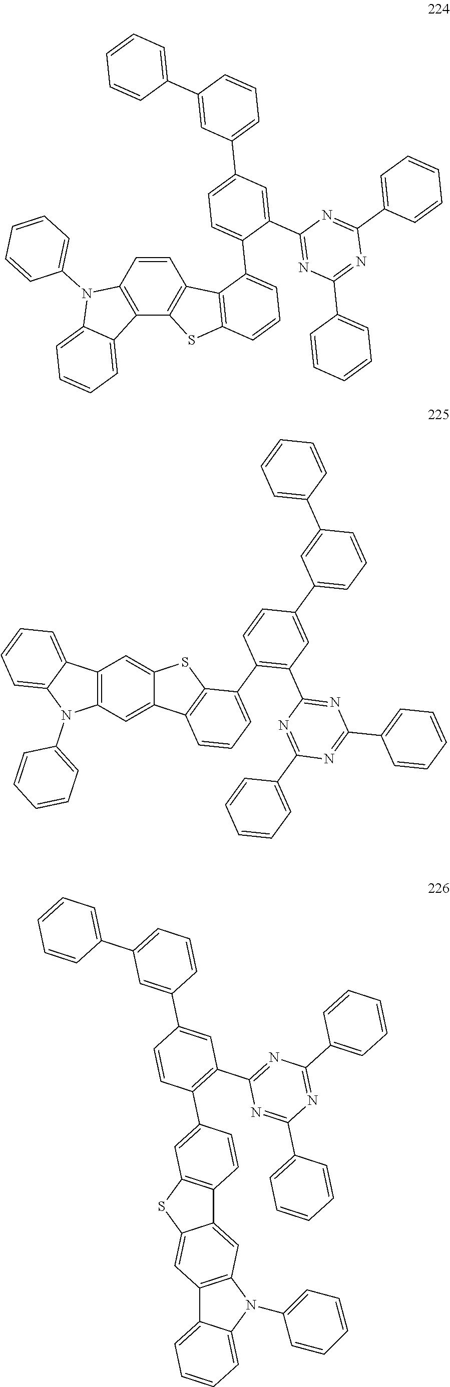 [SMILES: c1ccc(-c2cccc(-c3ccc(-c4cccc5sc6c(ccc7c6c6ccccc6n7-c6ccccc6)c45)c(-c4nc(-c5ccccc5)nc(-c5ccccc5)n4)c3)c2)cc1 ; c1ccc(-c2cccc(-c3ccc(-c4cccc5c4sc4cc6c7ccccc7n(-c7ccccc7)c6cc45)c(-c4nc(-c5ccccc5)nc(-c5ccccc5)n4)c3)c2)cc1 ; c1ccc(-c2cccc(-c3ccc(-c4ccc5c(c4)sc4cc6c7ccccc7n(-c7ccccc7)c6cc45)c(-c4nc(-c5ccccc5)nc(-c5ccccc5)n4)c3)c2)cc1]

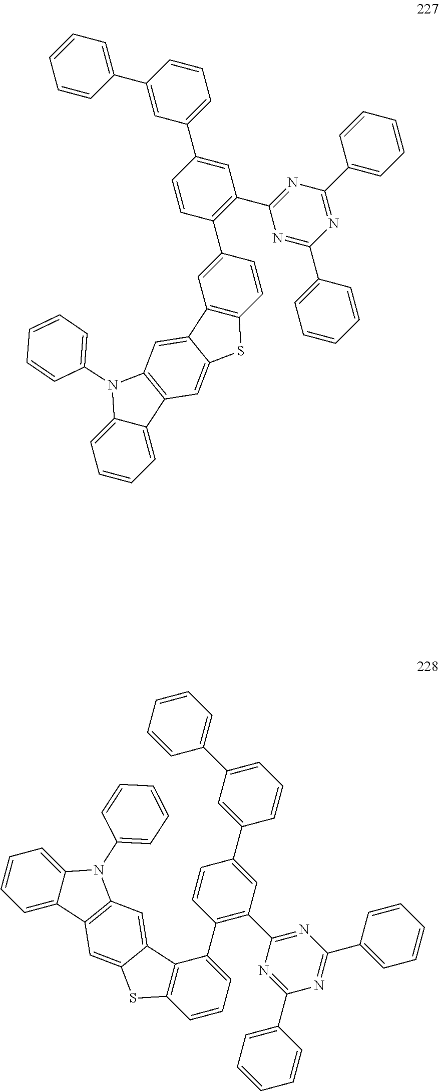 [SMILES: c1ccc(-c2cccc(-c3ccc(-c4ccc5sc6cc7c8ccccc8n(-c8ccccc8)c7cc6c5c4)c(-c4nc(-c5ccccc5)nc(-c5ccccc5)n4)c3)c2)cc1 ; c1ccc(-c2cccc(-c3ccc(-c4cccc5sc6cc7c8ccccc8n(-c8ccccc8)c7cc6c45)c(-c4nc(-c5ccccc5)nc(-c5ccccc5)n4)c3)c2)cc1]

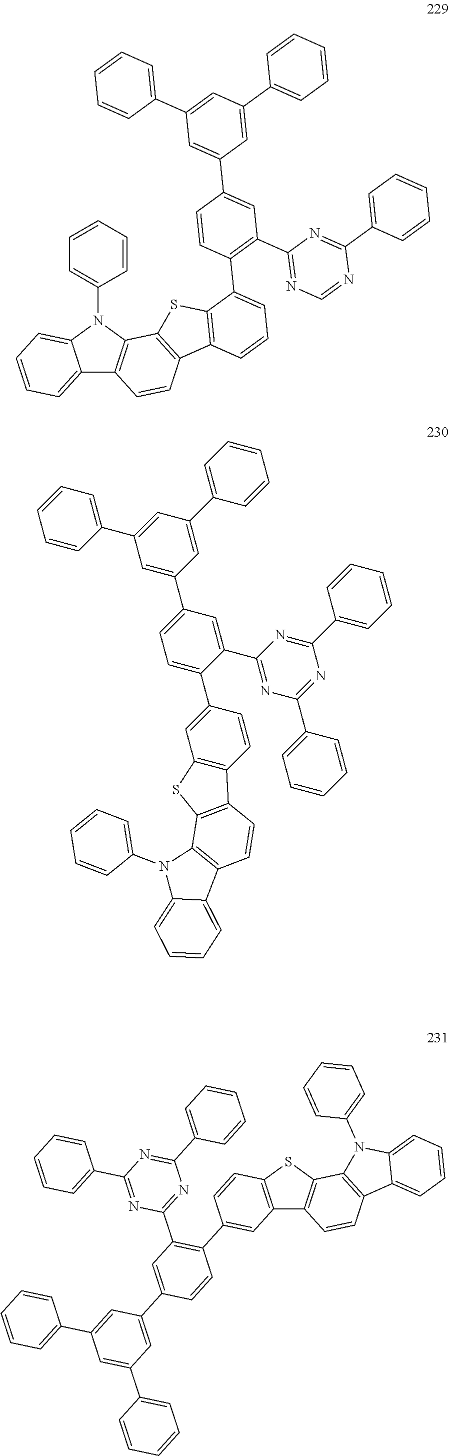 [SMILES: c1ccc(-c2cc(-c3ccccc3)cc(-c3ccc(-c4cccc5c4sc4c5ccc5c6ccccc6n(-c6ccccc6)c54)c(-c4ncnc(-c5ccccc5)n4)c3)c2)cc1 ; c1ccc(-c2cc(-c3ccccc3)cc(-c3ccc(-c4ccc5c(c4)sc4c5ccc5c6ccccc6n(-c6ccccc6)c54)c(-c4nc(-c5ccccc5)nc(-c5ccccc5)n4)c3)c2)cc1 ; c1ccc(-c2cc(-c3ccccc3)cc(-c3ccc(-c4ccc5sc6c(ccc7c8ccccc8n(-c8ccccc8)c76)c5c4)c(-c4nc(-c5ccccc5)nc(-c5ccccc5)n4)c3)c2)cc1]

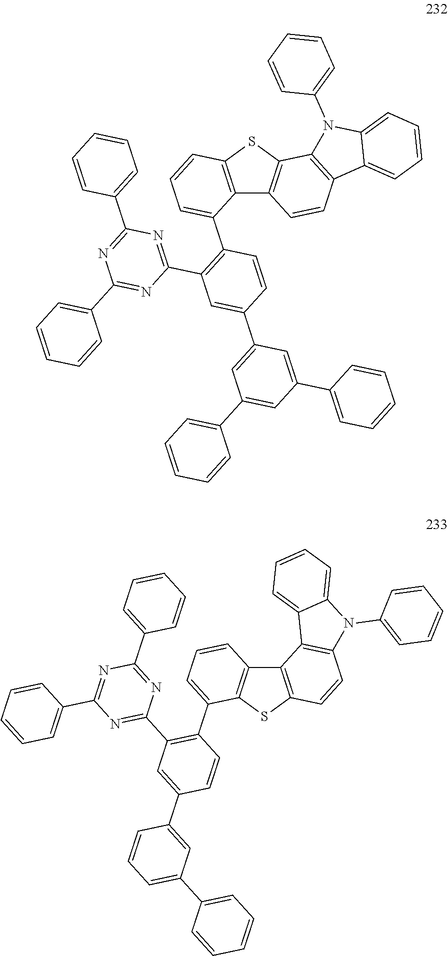 [SMILES: c1ccc(-c2cc(-c3ccccc3)cc(-c3ccc(-c4cccc5sc6c(ccc7c8ccccc8n(-c8ccccc8)c76)c45)c(-c4nc(-c5ccccc5)nc(-c5ccccc5)n4)c3)c2)cc1 ; c1ccc(-c2cccc(-c3ccc(-c4cccc5c4sc4ccc6c(c7ccccc7n6-c6ccccc6)c45)c(-c4nc(-c5ccccc5)nc(-c5ccccc5)n4)c3)c2)cc1]

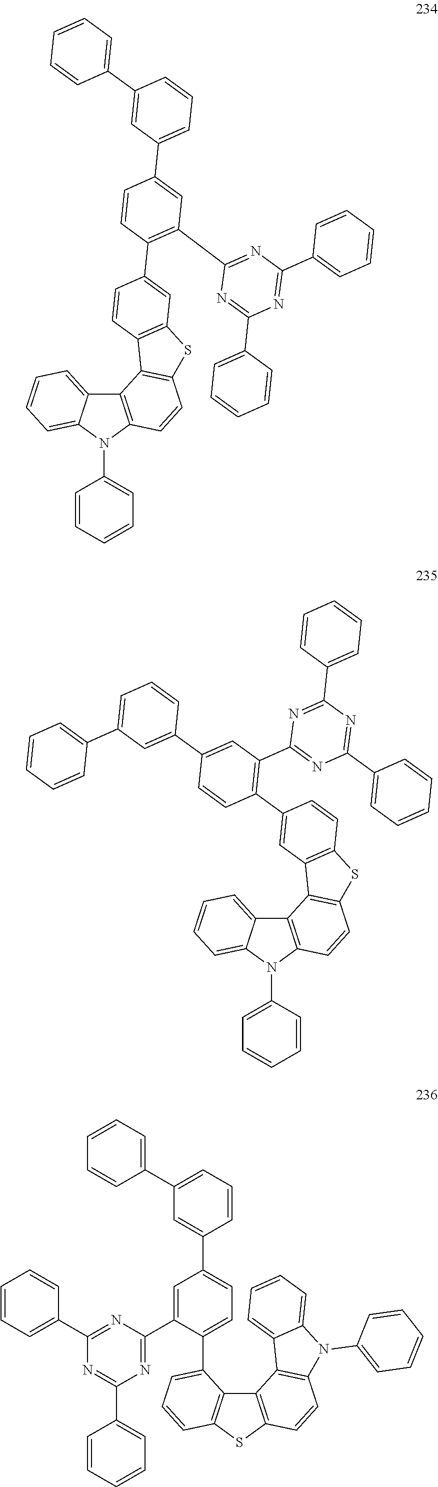 [SMILES: c1ccc(-c2cccc(-c3ccc(-c4ccc5c(c4)sc4ccc6c(c7ccccc7n6-c6ccccc6)c45)c(-c4nc(-c5ccccc5)nc(-c5ccccc5)n4)c3)c2)cc1 ; c1ccc(-c2cccc(-c3ccc(-c4ccc5sc6ccc7c(c8ccccc8n7-c7ccccc7)c6c5c4)c(-c4nc(-c5ccccc5)nc(-c5ccccc5)n4)c3)c2)cc1 ; c1ccc(-c2cccc(-c3ccc(-c4cccc5sc6ccc7c(c8ccccc8n7-c7ccccc7)c6c45)c(-c4nc(-c5ccccc5)nc(-c5ccccc5)n4)c3)c2)cc1]

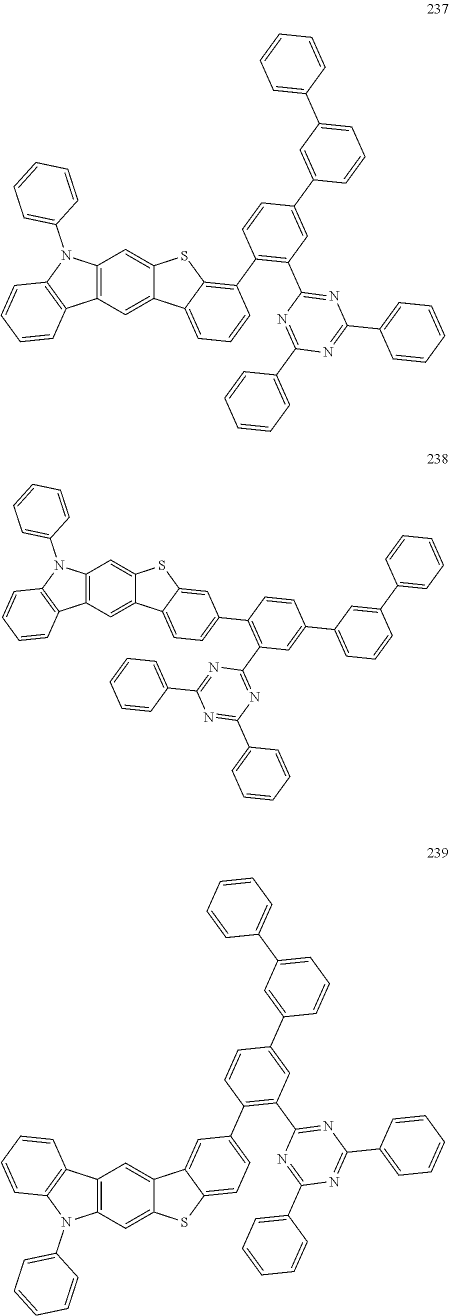 [SMILES: c1ccc(-c2cccc(-c3ccc(-c4cccc5c4sc4cc6c(cc45)c4ccccc4n6-c4ccccc4)c(-c4nc(-c5ccccc5)nc(-c5ccccc5)n4)c3)c2)cc1 ; c1ccc(-c2cccc(-c3ccc(-c4ccc5c(c4)sc4cc6c(cc45)c4ccccc4n6-c4ccccc4)c(-c4nc(-c5ccccc5)nc(-c5ccccc5)n4)c3)c2)cc1 ; c1ccc(-c2cccc(-c3ccc(-c4ccc5sc6cc7c(cc6c5c4)c4ccccc4n7-c4ccccc4)c(-c4nc(-c5ccccc5)nc(-c5ccccc5)n4)c3)c2)cc1]

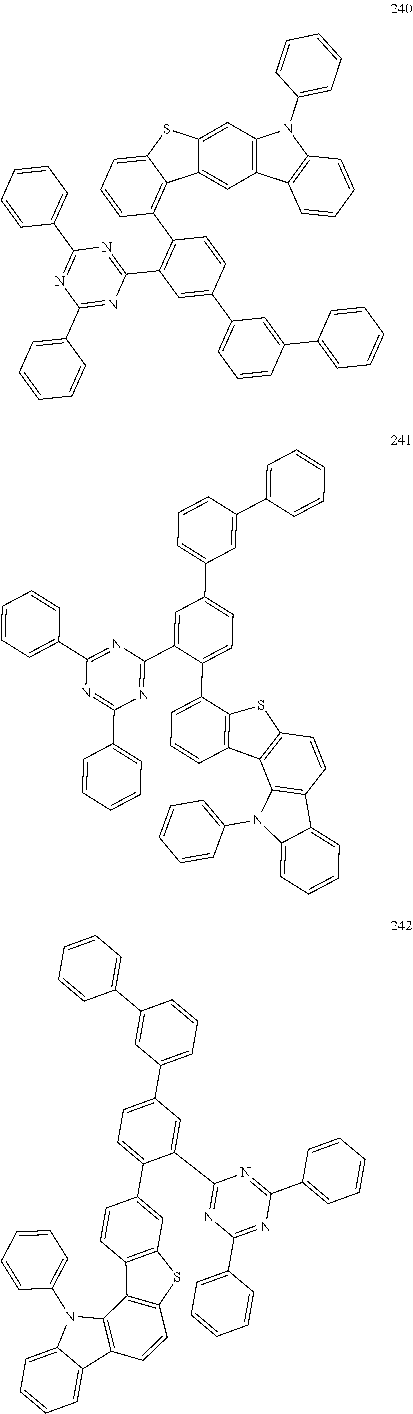 [SMILES: c1ccc(-c2cccc(-c3ccc(-c4cccc5sc6cc7c(cc6c45)c4ccccc4n7-c4ccccc4)c(-c4nc(-c5ccccc5)nc(-c5ccccc5)n4)c3)c2)cc1 ; c1ccc(-c2cccc(-c3ccc(-c4cccc5c4sc4ccc6c7ccccc7n(-c7ccccc7)c6c45)c(-c4nc(-c5ccccc5)nc(-c5ccccc5)n4)c3)c2)cc1 ; c1ccc(-c2cccc(-c3ccc(-c4ccc5c(c4)sc4ccc6c7ccccc7n(-c7ccccc7)c6c45)c(-c4nc(-c5ccccc5)nc(-c5ccccc5)n4)c3)c2)cc1]

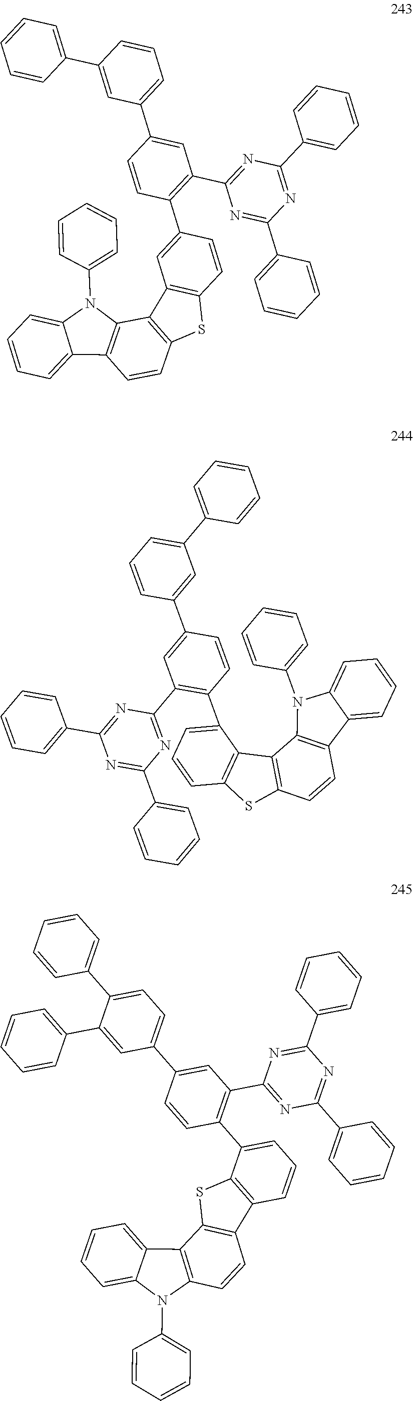 [SMILES: c1ccc(-c2cccc(-c3ccc(-c4ccc5sc6ccc7c8ccccc8n(-c8ccccc8)c7c6c5c4)c(-c4nc(-c5ccccc5)nc(-c5ccccc5)n4)c3)c2)cc1 ; c1ccc(-c2cccc(-c3ccc(-c4cccc5sc6ccc7c8ccccc8n(-c8ccccc8)c7c6c45)c(-c4nc(-c5ccccc5)nc(-c5ccccc5)n4)c3)c2)cc1 ; c1ccc(-c2nc(-c3ccccc3)nc(-c3cc(-c4ccc(-c5ccccc5)c(-c5ccccc5)c4)ccc3-c3cccc4c3sc3c4ccc4c3c3ccccc3n4-c3ccccc3)n2)cc1]

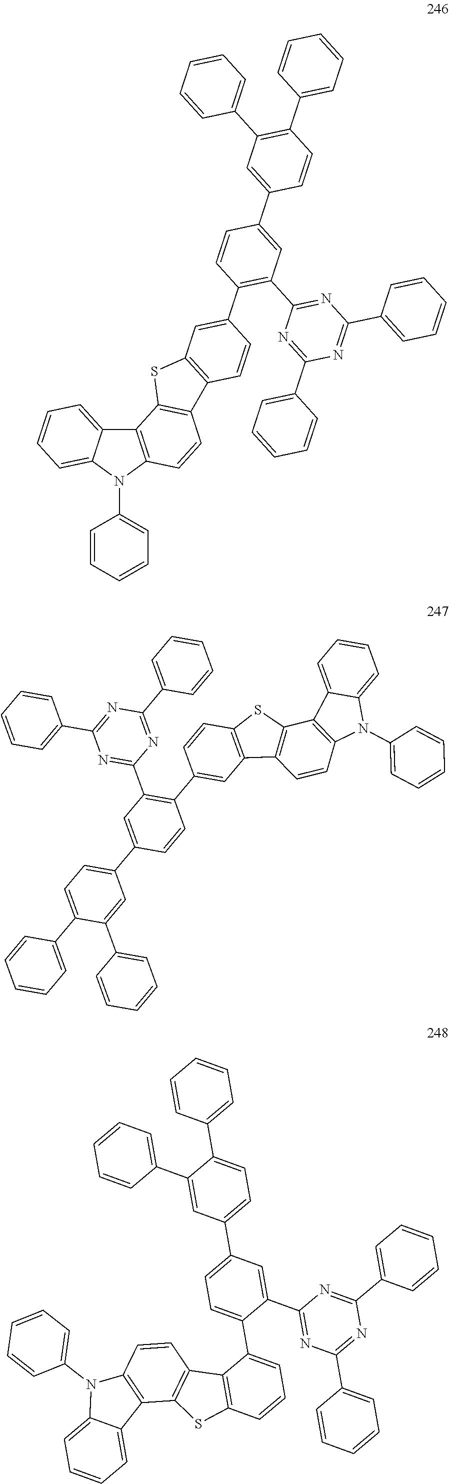 [SMILES: c1ccc(-c2nc(-c3ccccc3)nc(-c3cc(-c4ccc(-c5ccccc5)c(-c5ccccc5)c4)ccc3-c3ccc4c(c3)sc3c4ccc4c3c3ccccc3n4-c3ccccc3)n2)cc1 ; c1ccc(-c2nc(-c3ccccc3)nc(-c3cc(-c4ccc(-c5ccccc5)c(-c5ccccc5)c4)ccc3-c3ccc4sc5c(ccc6c5c5ccccc5n6-c5ccccc5)c4c3)n2)cc1 ; c1ccc(-c2nc(-c3ccccc3)nc(-c3cc(-c4ccc(-c5ccccc5)c(-c5ccccc5)c4)ccc3-c3cccc4sc5c(ccc6c5c5ccccc5n6-c5ccccc5)c34)n2)cc1]

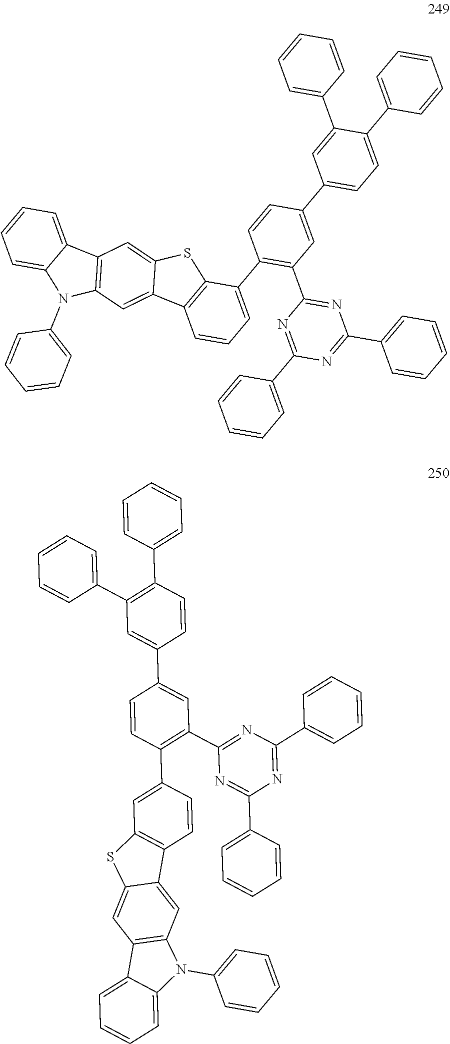 [SMILES: c1ccc(-c2nc(-c3ccccc3)nc(-c3cc(-c4ccc(-c5ccccc5)c(-c5ccccc5)c4)ccc3-c3cccc4c3sc3cc5c6ccccc6n(-c6ccccc6)c5cc34)n2)cc1 ; c1ccc(-c2nc(-c3ccccc3)nc(-c3cc(-c4ccc(-c5ccccc5)c(-c5ccccc5)c4)ccc3-c3ccc4c(c3)sc3cc5c6ccccc6n(-c6ccccc6)c5cc34)n2)cc1]

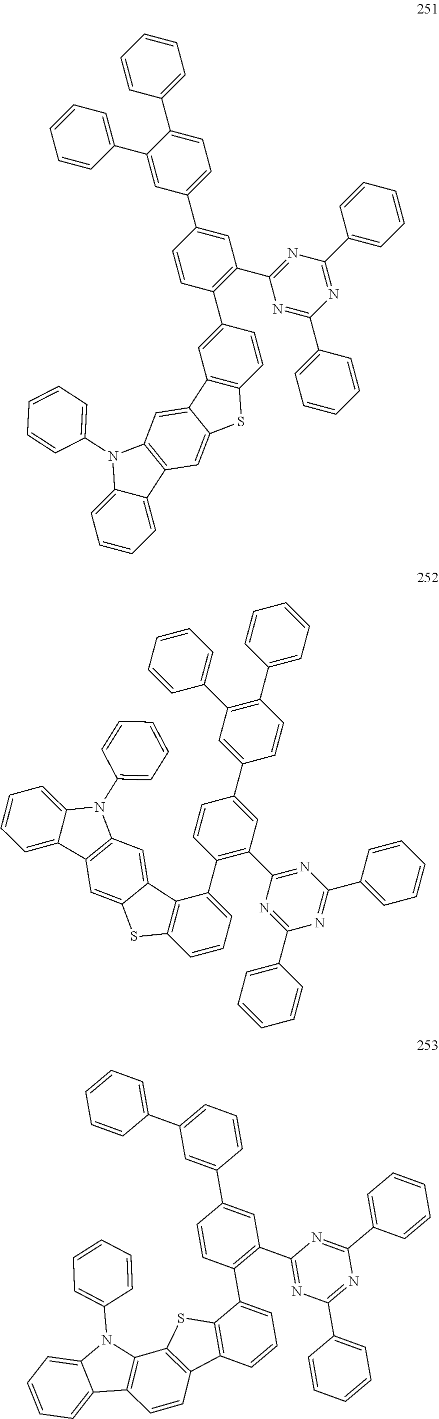 [SMILES: c1ccc(-c2nc(-c3ccccc3)nc(-c3cc(-c4ccc(-c5ccccc5)c(-c5ccccc5)c4)ccc3-c3ccc4sc5cc6c7ccccc7n(-c7ccccc7)c6cc5c4c3)n2)cc1 ; c1ccc(-c2nc(-c3ccccc3)nc(-c3cc(-c4ccc(-c5ccccc5)c(-c5ccccc5)c4)ccc3-c3cccc4sc5cc6c7ccccc7n(-c7ccccc7)c6cc5c34)n2)cc1 ; c1ccc(-c2cccc(-c3ccc(-c4cccc5c4sc4c5ccc5c6ccccc6n(-c6ccccc6)c54)c(-c4nc(-c5ccccc5)nc(-c5ccccc5)n4)c3)c2)cc1]

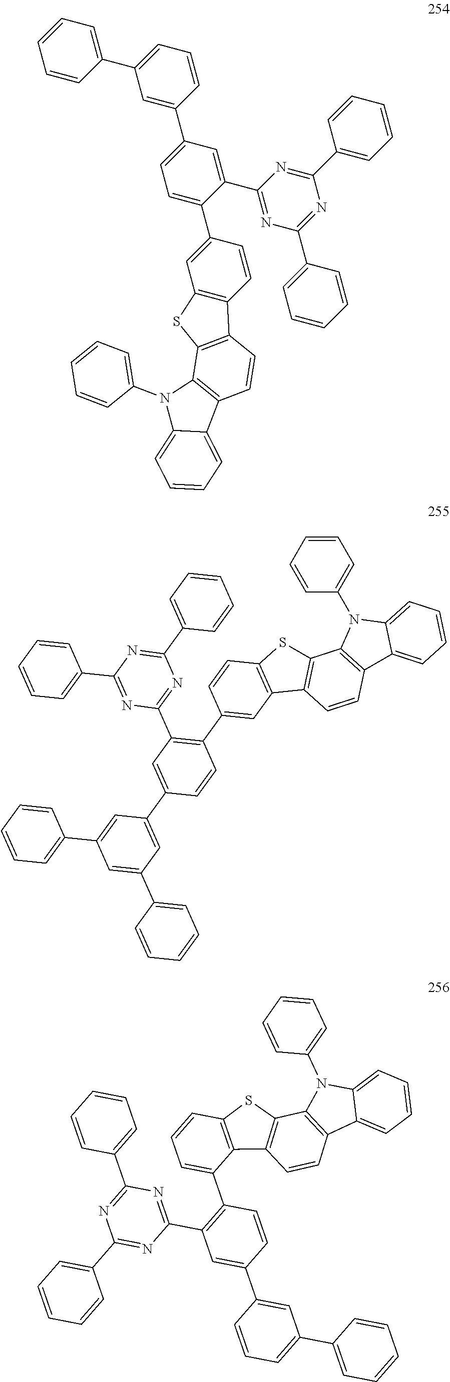 [SMILES: c1ccc(-c2cccc(-c3ccc(-c4ccc5c(c4)sc4c5ccc5c6ccccc6n(-c6ccccc6)c54)c(-c4nc(-c5ccccc5)nc(-c5ccccc5)n4)c3)c2)cc1 ; c1ccc(-c2cc(-c3ccccc3)cc(-c3ccc(-c4ccc5sc6c(ccc7c8ccccc8n(-c8ccccc8)c76)c5c4)c(-c4nc(-c5ccccc5)nc(-c5ccccc5)n4)c3)c2)cc1 ; c1ccc(-c2cccc(-c3ccc(-c4cccc5sc6c(ccc7c8ccccc8n(-c8ccccc8)c76)c45)c(-c4nc(-c5ccccc5)nc(-c5ccccc5)n4)c3)c2)cc1]

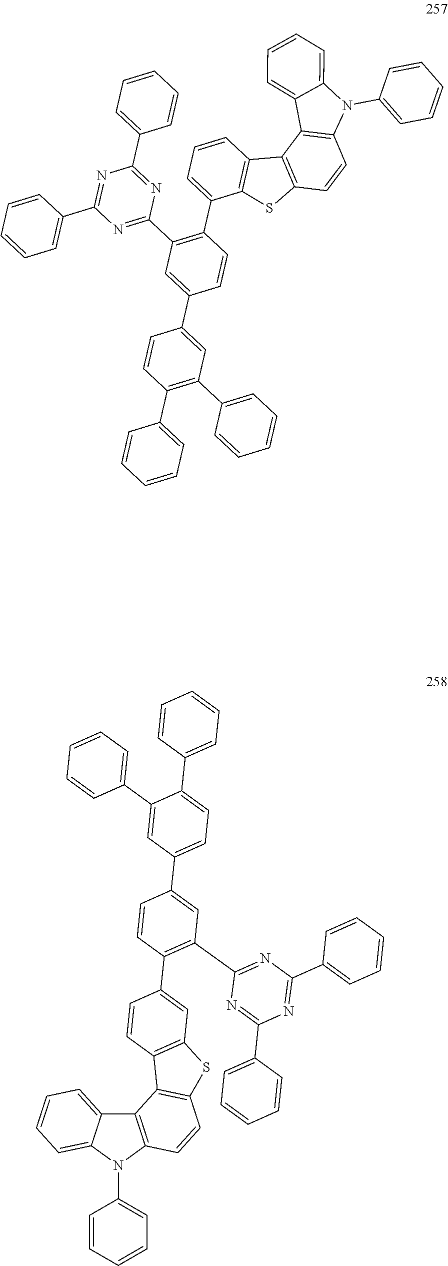 [SMILES: c1ccc(-c2nc(-c3ccccc3)nc(-c3cc(-c4ccc(-c5ccccc5)c(-c5ccccc5)c4)ccc3-c3cccc4c3sc3ccc5c(c6ccccc6n5-c5ccccc5)c34)n2)cc1 ; c1ccc(-c2nc(-c3ccccc3)nc(-c3cc(-c4ccc(-c5ccccc5)c(-c5ccccc5)c4)ccc3-c3ccc4c(c3)sc3ccc5c(c6ccccc6n5-c5ccccc5)c34)n2)cc1]

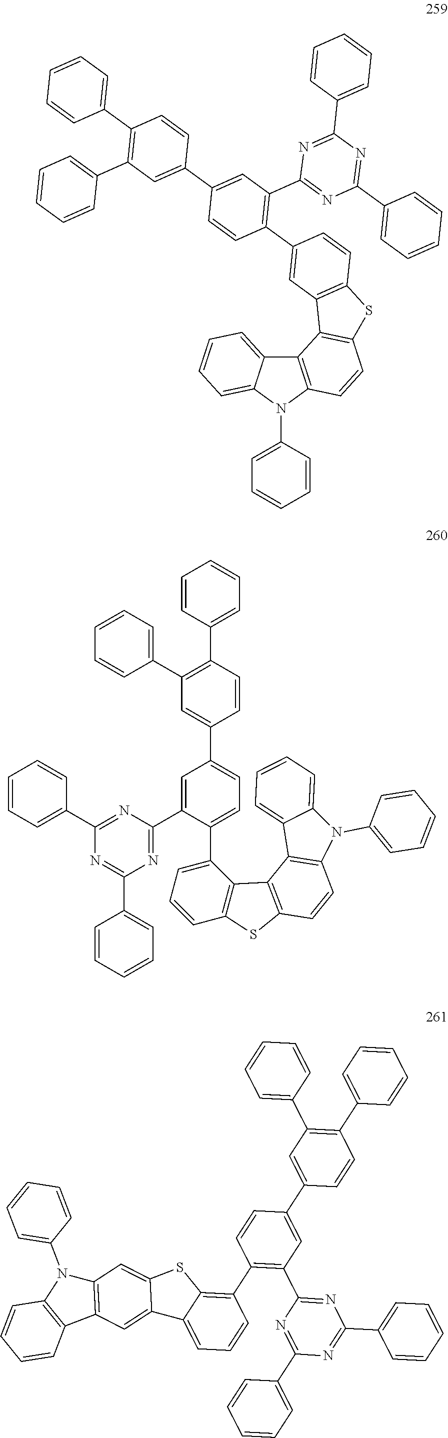 [SMILES: c1ccc(-c2nc(-c3ccccc3)nc(-c3cc(-c4ccc(-c5ccccc5)c(-c5ccccc5)c4)ccc3-c3ccc4sc5ccc6c(c7ccccc7n6-c6ccccc6)c5c4c3)n2)cc1 ; c1ccc(-c2nc(-c3ccccc3)nc(-c3cc(-c4ccc(-c5ccccc5)c(-c5ccccc5)c4)ccc3-c3cccc4sc5ccc6c(c7ccccc7n6-c6ccccc6)c5c34)n2)cc1 ; c1ccc(-c2nc(-c3ccccc3)nc(-c3cc(-c4ccc(-c5ccccc5)c(-c5ccccc5)c4)ccc3-c3cccc4c3sc3cc5c(cc34)c3ccccc3n5-c3ccccc3)n2)cc1]

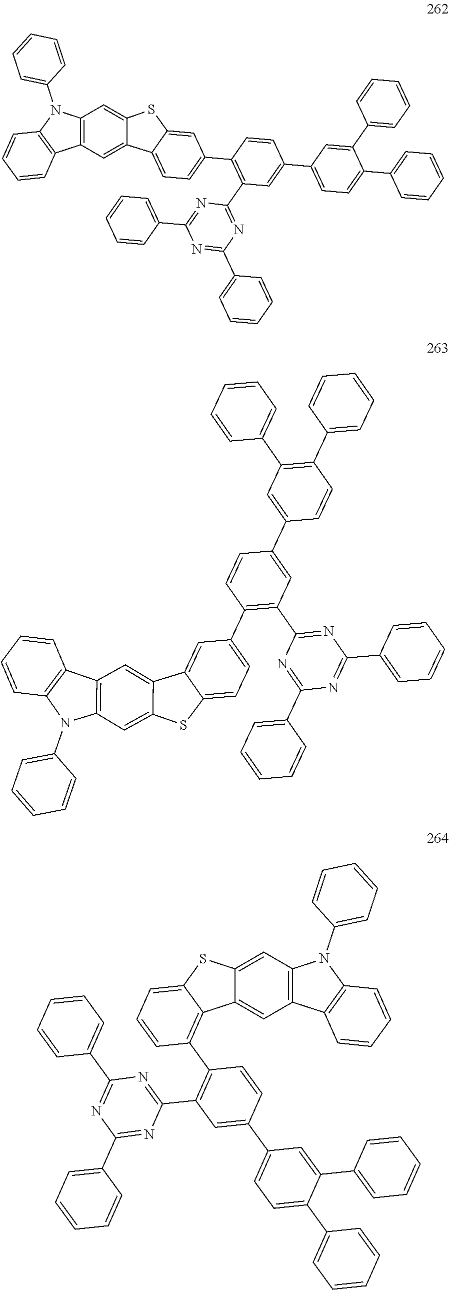 [SMILES: c1ccc(-c2nc(-c3ccccc3)nc(-c3cc(-c4ccc(-c5ccccc5)c(-c5ccccc5)c4)ccc3-c3ccc4c(c3)sc3cc5c(cc34)c3ccccc3n5-c3ccccc3)n2)cc1 ; c1ccc(-c2nc(-c3ccccc3)nc(-c3cc(-c4ccc(-c5ccccc5)c(-c5ccccc5)c4)ccc3-c3ccc4sc5cc6c(cc5c4c3)c3ccccc3n6-c3ccccc3)n2)cc1 ; c1ccc(-c2nc(-c3ccccc3)nc(-c3cc(-c4ccc(-c5ccccc5)c(-c5ccccc5)c4)ccc3-c3cccc4sc5cc6c(cc5c34)c3ccccc3n6-c3ccccc3)n2)cc1]

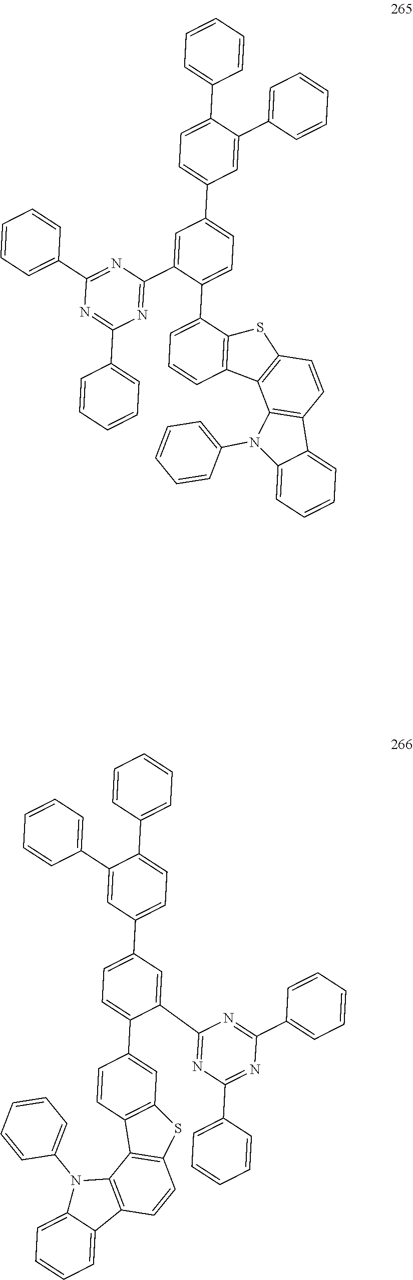 [SMILES: c1ccc(-c2nc(-c3ccccc3)nc(-c3cc(-c4ccc(-c5ccccc5)c(-c5ccccc5)c4)ccc3-c3cccc4c3sc3ccc5c6ccccc6n(-c6ccccc6)c5c34)n2)cc1 ; c1ccc(-c2nc(-c3ccccc3)nc(-c3cc(-c4ccc(-c5ccccc5)c(-c5ccccc5)c4)ccc3-c3ccc4c(c3)sc3ccc5c6ccccc6n(-c6ccccc6)c5c34)n2)cc1]

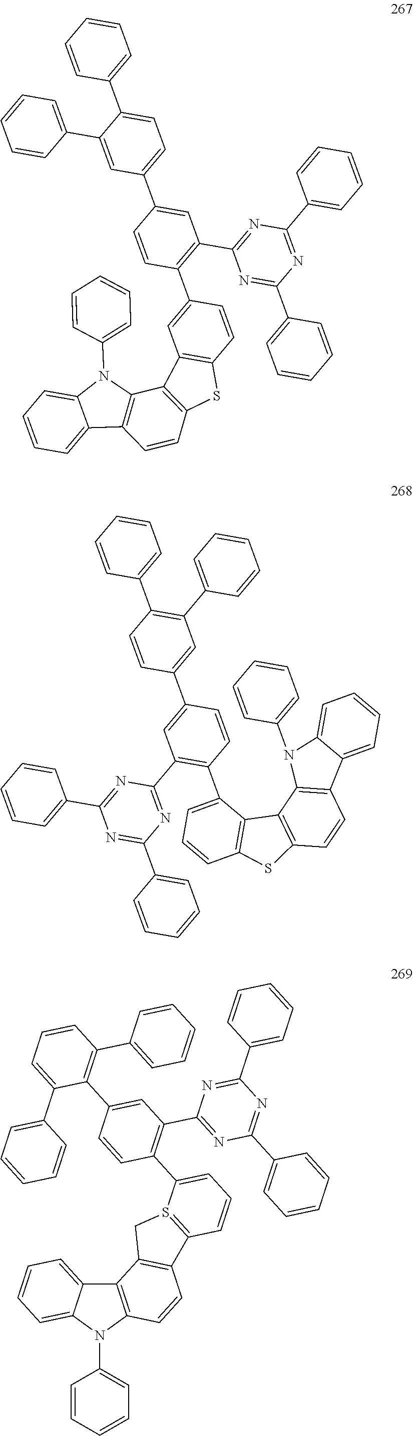 [SMILES: c1ccc(-c2nc(-c3ccccc3)nc(-c3cc(-c4ccc(-c5ccccc5)c(-c5ccccc5)c4)ccc3-c3ccc4sc5ccc6c7ccccc7n(-c7ccccc7)c6c5c4c3)n2)cc1 ; c1ccc(-c2nc(-c3ccccc3)nc(-c3cc(-c4ccc(-c5ccccc5)c(-c5ccccc5)c4)ccc3-c3cccc4sc5ccc6c7ccccc7n(-c7ccccc7)c6c5c34)n2)cc1 ; C1=CC2=S(Cc3c2ccc2c3c3ccccc3n2-c2ccccc2)C(c2ccc(-c3c(-c4ccccc4)cccc3-c3ccccc3)cc2-c2nc(-c3ccccc3)nc(-c3ccccc3)n2)=C1]

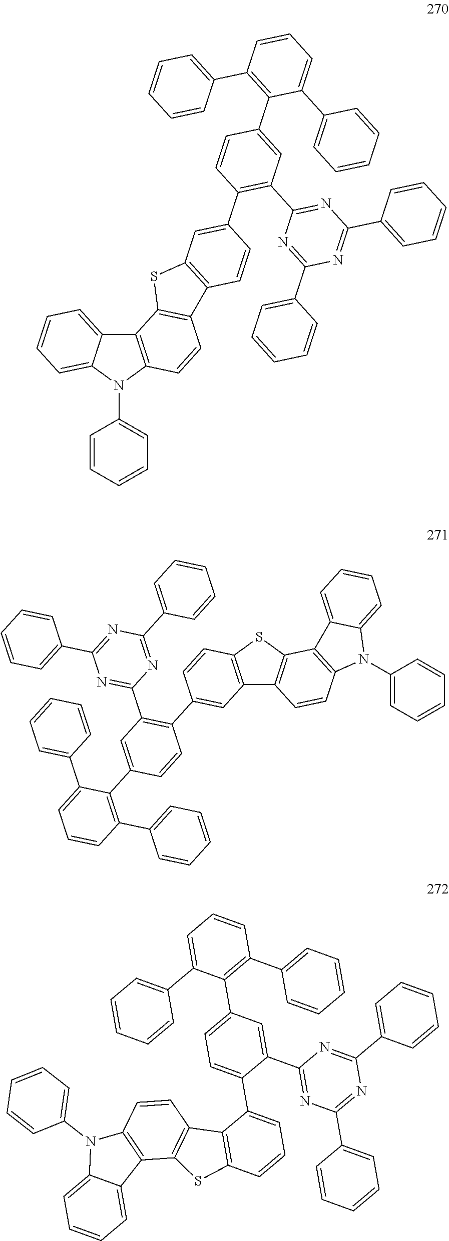 [SMILES: c1ccc(-c2nc(-c3ccccc3)nc(-c3cc(-c4c(-c5ccccc5)cccc4-c4ccccc4)ccc3-c3ccc4c(c3)sc3c4ccc4c3c3ccccc3n4-c3ccccc3)n2)cc1 ; c1ccc(-c2nc(-c3ccccc3)nc(-c3cc(-c4c(-c5ccccc5)cccc4-c4ccccc4)ccc3-c3ccc4sc5c(ccc6c5c5ccccc5n6-c5ccccc5)c4c3)n2)cc1 ; c1ccc(-c2nc(-c3ccccc3)nc(-c3cc(-c4c(-c5ccccc5)cccc4-c4ccccc4)ccc3-c3cccc4sc5c(ccc6c5c5ccccc5n6-c5ccccc5)c34)n2)cc1]

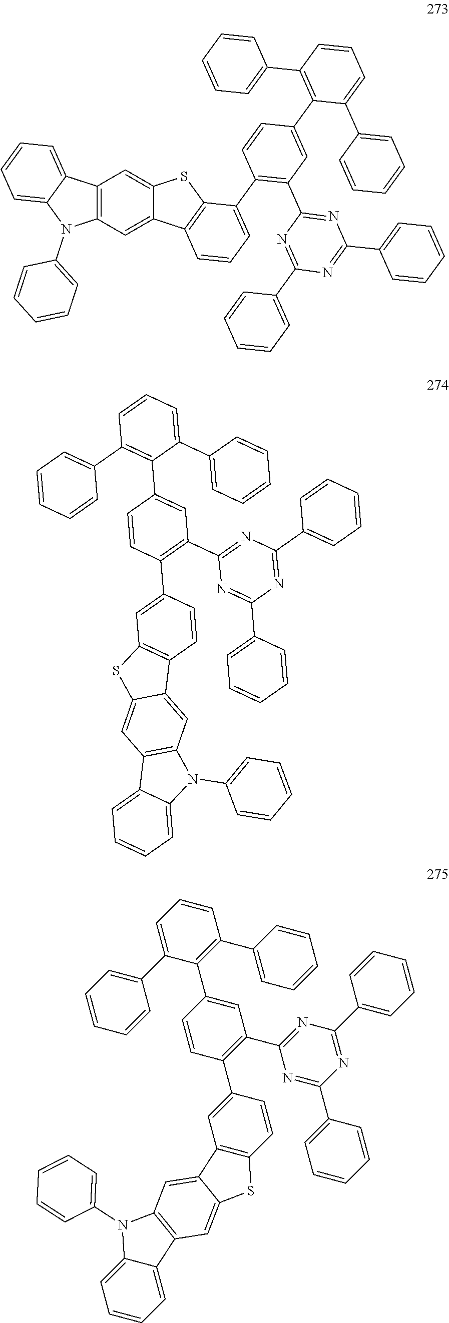 [SMILES: c1ccc(-c2nc(-c3ccccc3)nc(-c3cc(-c4c(-c5ccccc5)cccc4-c4ccccc4)ccc3-c3cccc4c3sc3cc5c6ccccc6n(-c6ccccc6)c5cc34)n2)cc1 ; c1ccc(-c2nc(-c3ccccc3)nc(-c3cc(-c4c(-c5ccccc5)cccc4-c4ccccc4)ccc3-c3ccc4c(c3)sc3cc5c6ccccc6n(-c6ccccc6)c5cc34)n2)cc1 ; c1ccc(-c2nc(-c3ccccc3)nc(-c3cc(-c4c(-c5ccccc5)cccc4-c4ccccc4)ccc3-c3ccc4sc5cc6c7ccccc7n(-c7ccccc7)c6cc5c4c3)n2)cc1]

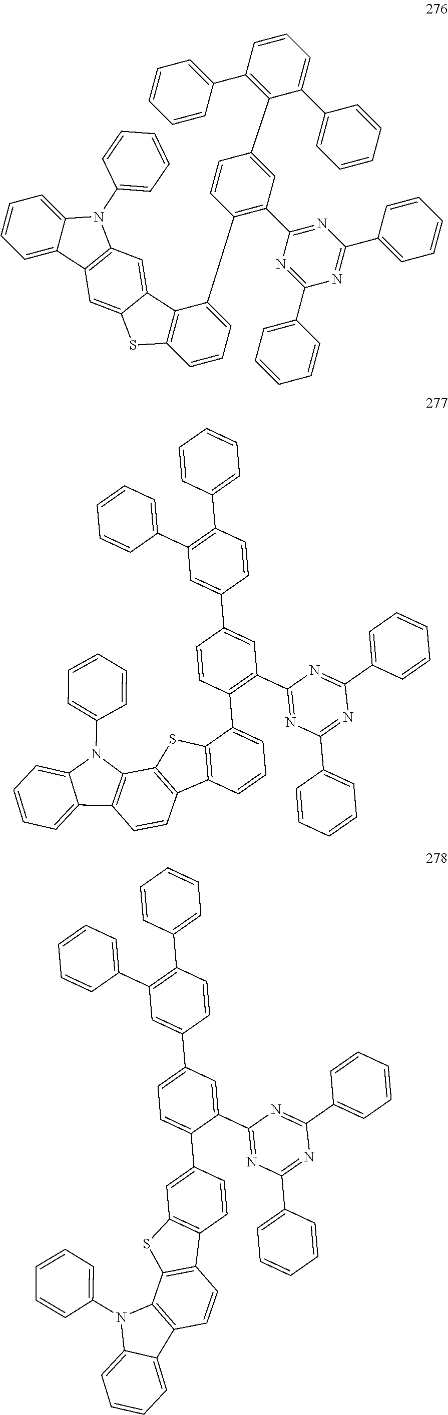

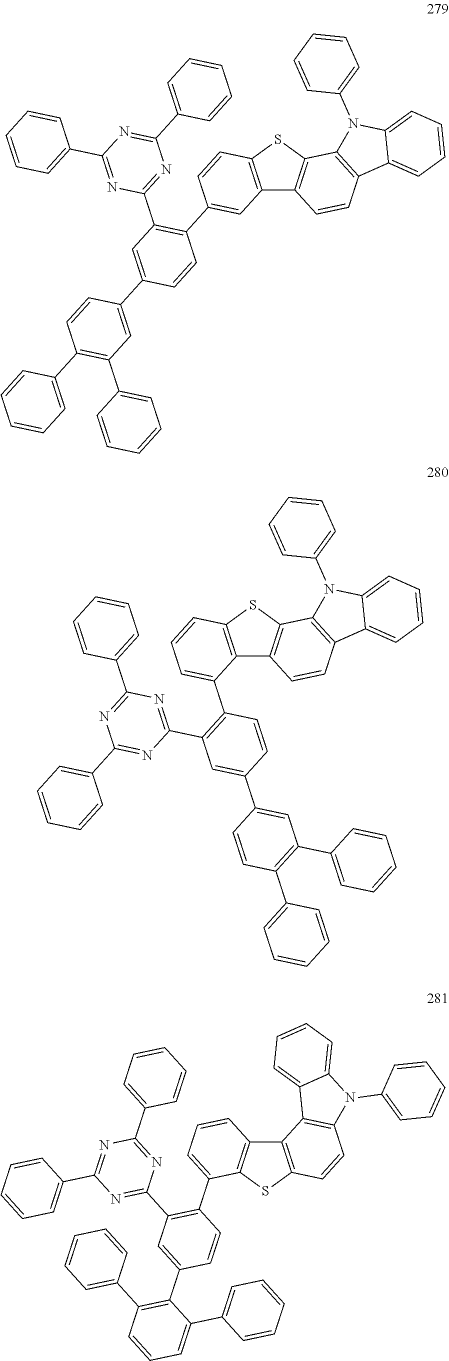 [SMILES: c1ccc(-c2nc(-c3ccccc3)nc(-c3cc(-c4ccc(-c5ccccc5)c(-c5ccccc5)c4)ccc3-c3ccc4sc5c(ccc6c7ccccc7n(-c7ccccc7)c65)c4c3)n2)cc1 ; c1ccc(-c2nc(-c3ccccc3)nc(-c3cc(-c4ccc(-c5ccccc5)c(-c5ccccc5)c4)ccc3-c3cccc4sc5c(ccc6c7ccccc7n(-c7ccccc7)c65)c34)n2)cc1 ; c1ccc(-c2nc(-c3ccccc3)nc(-c3cc(-c4c(-c5ccccc5)cccc4-c4ccccc4)ccc3-c3cccc4c3sc3ccc5c(c6ccccc6n5-c5ccccc5)c34)n2)cc1]

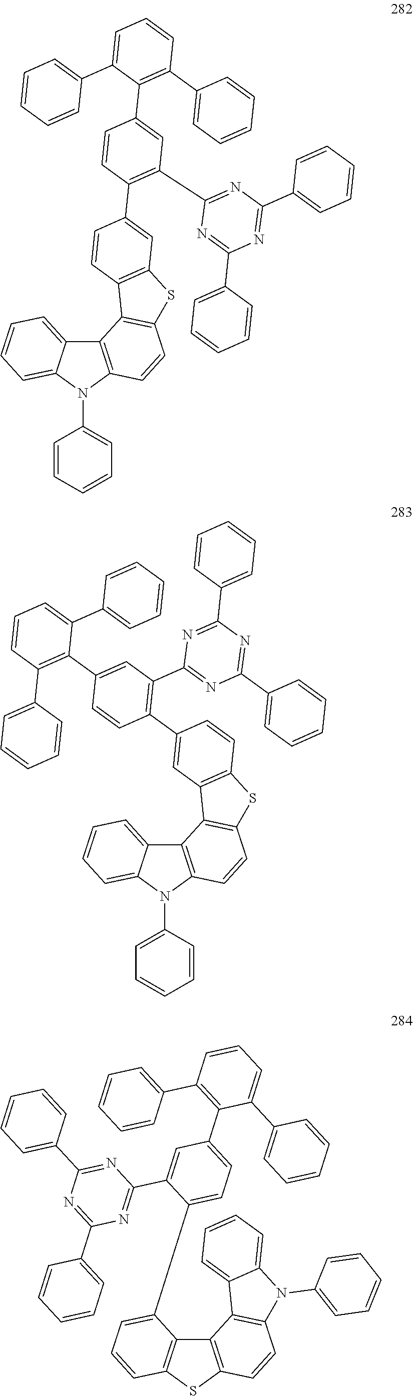 [SMILES: c1ccc(-c2nc(-c3ccccc3)nc(-c3cc(-c4c(-c5ccccc5)cccc4-c4ccccc4)ccc3-c3ccc4c(c3)sc3ccc5c(c6ccccc6n5-c5ccccc5)c34)n2)cc1 ; c1ccc(-c2nc(-c3ccccc3)nc(-c3cc(-c4c(-c5ccccc5)cccc4-c4ccccc4)ccc3-c3ccc4sc5ccc6c(c7ccccc7n6-c6ccccc6)c5c4c3)n2)cc1 ; c1ccc(-c2nc(-c3ccccc3)nc(-c3cc(-c4c(-c5ccccc5)cccc4-c4ccccc4)ccc3-c3cccc4sc5ccc6c(c7ccccc7n6-c6ccccc6)c5c34)n2)cc1]

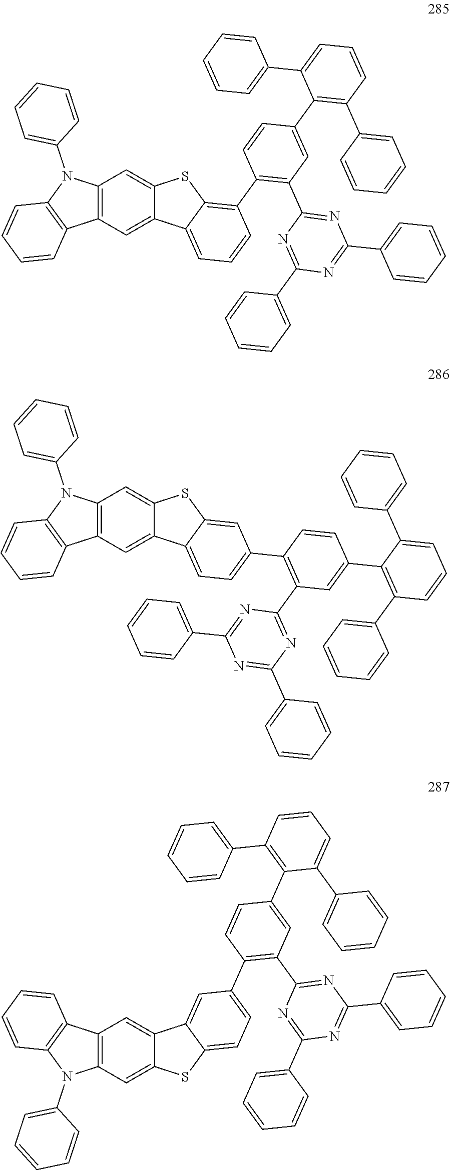 [SMILES: c1ccc(-c2nc(-c3ccccc3)nc(-c3cc(-c4c(-c5ccccc5)cccc4-c4ccccc4)ccc3-c3cccc4c3sc3cc5c(cc34)c3ccccc3n5-c3ccccc3)n2)cc1 ; c1ccc(-c2nc(-c3ccccc3)nc(-c3cc(-c4c(-c5ccccc5)cccc4-c4ccccc4)ccc3-c3ccc4c(c3)sc3cc5c(cc34)c3ccccc3n5-c3ccccc3)n2)cc1 ; c1ccc(-c2nc(-c3ccccc3)nc(-c3cc(-c4c(-c5ccccc5)cccc4-c4ccccc4)ccc3-c3ccc4sc5cc6c(cc5c4c3)c3ccccc3n6-c3ccccc3)n2)cc1]

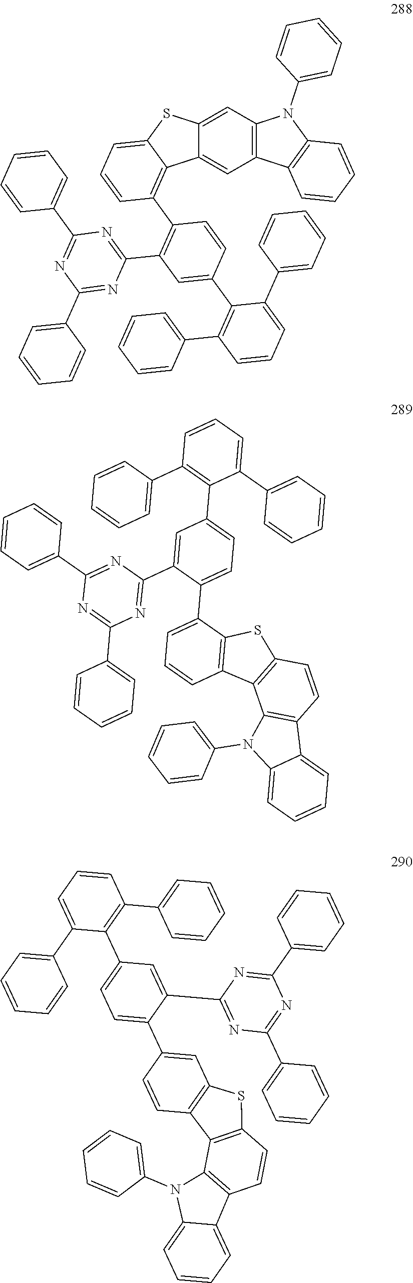 [SMILES: c1ccc(-c2nc(-c3ccccc3)nc(-c3cc(-c4c(-c5ccccc5)cccc4-c4ccccc4)ccc3-c3cccc4sc5cc6c(cc5c34)c3ccccc3n6-c3ccccc3)n2)cc1 ; c1ccc(-c2nc(-c3ccccc3)nc(-c3cc(-c4c(-c5ccccc5)cccc4-c4ccccc4)ccc3-c3cccc4c3sc3ccc5c6ccccc6n(-c6ccccc6)c5c34)n2)cc1 ; c1ccc(-c2nc(-c3ccccc3)nc(-c3cc(-c4c(-c5ccccc5)cccc4-c4ccccc4)ccc3-c3ccc4c(c3)sc3ccc5c6ccccc6n(-c6ccccc6)c5c34)n2)cc1]

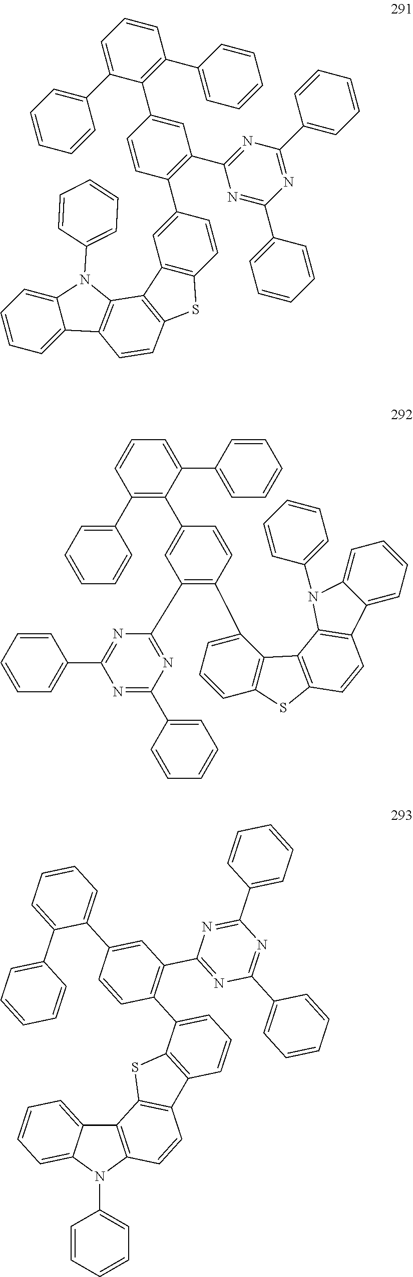 [SMILES: c1ccc(-c2nc(-c3ccccc3)nc(-c3cc(-c4c(-c5ccccc5)cccc4-c4ccccc4)ccc3-c3ccc4sc5ccc6c7ccccc7n(-c7ccccc7)c6c5c4c3)n2)cc1 ; c1ccc(-c2nc(-c3ccccc3)nc(-c3cc(-c4c(-c5ccccc5)cccc4-c4ccccc4)ccc3-c3cccc4sc5ccc6c7ccccc7n(-c7ccccc7)c6c5c34)n2)cc1 ; c1ccc(-c2nc(-c3ccccc3)nc(-c3cc(-c4ccccc4-c4ccccc4)ccc3-c3cccc4c3sc3c4ccc4c3c3ccccc3n4-c3ccccc3)n2)cc1]

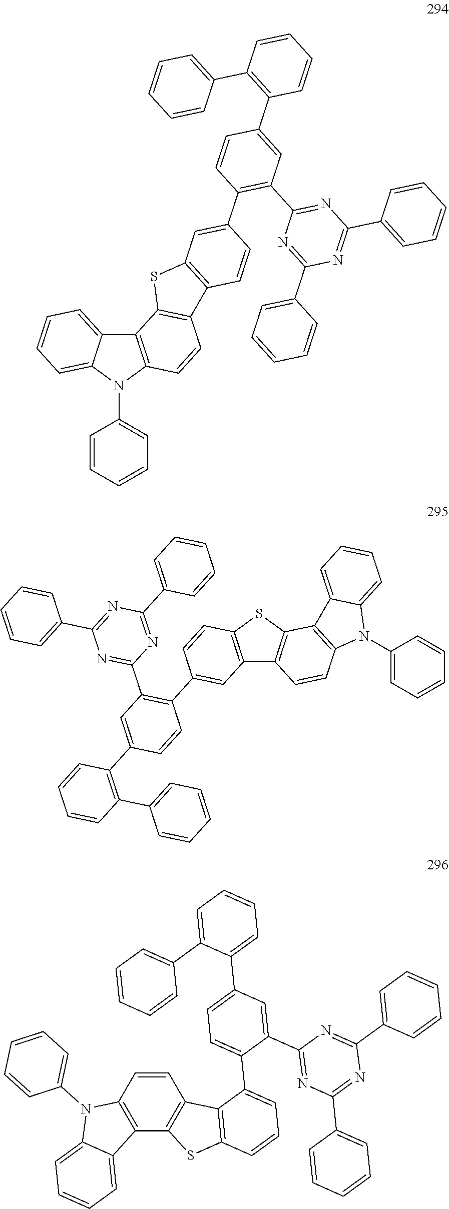 [SMILES: c1ccc(-c2nc(-c3ccccc3)nc(-c3cc(-c4ccccc4-c4ccccc4)ccc3-c3ccc4c(c3)sc3c4ccc4c3c3ccccc3n4-c3ccccc3)n2)cc1 ; c1ccc(-c2nc(-c3ccccc3)nc(-c3cc(-c4ccccc4-c4ccccc4)ccc3-c3ccc4sc5c(ccc6c5c5ccccc5n6-c5ccccc5)c4c3)n2)cc1 ; c1ccc(-c2nc(-c3ccccc3)nc(-c3cc(-c4ccccc4-c4ccccc4)ccc3-c3cccc4sc5c(ccc6c5c5ccccc5n6-c5ccccc5)c34)n2)cc1]

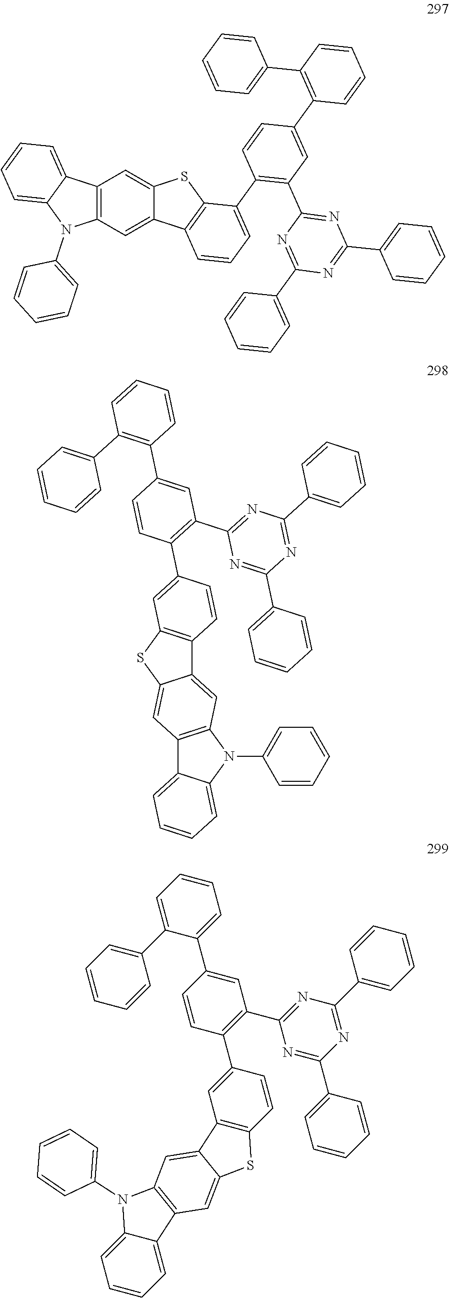

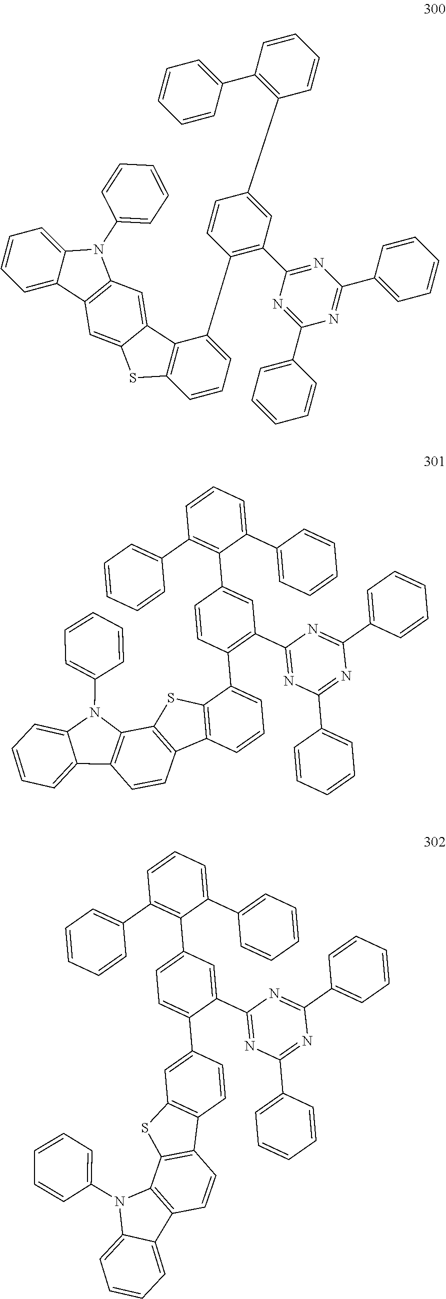 [SMILES: c1ccc(-c2nc(-c3ccccc3)nc(-c3cc(-c4ccccc4-c4ccccc4)ccc3-c3cccc4sc5cc6c7ccccc7n(-c7ccccc7)c6cc5c34)n2)cc1 ; c1ccc(-c2nc(-c3ccccc3)nc(-c3cc(-c4c(-c5ccccc5)cccc4-c4ccccc4)ccc3-c3cccc4c3sc3c4ccc4c5ccccc5n(-c5ccccc5)c43)n2)cc1 ; c1ccc(-c2nc(-c3ccccc3)nc(-c3cc(-c4c(-c5ccccc5)cccc4-c4ccccc4)ccc3-c3ccc4c(c3)sc3c4ccc4c5ccccc5n(-c5ccccc5)c43)n2)cc1]

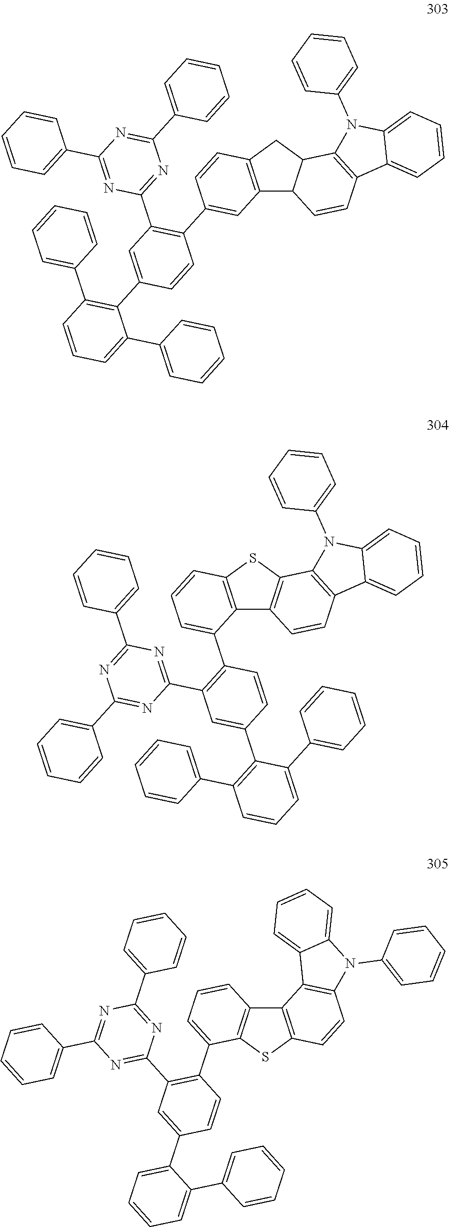 [SMILES: C1=CC2c3cc(-c4ccc(-c5c(-c6ccccc6)cccc5-c5ccccc5)cc4-c4nc(-c5ccccc5)nc(-c5ccccc5)n4)ccc3CC2c2c1c1ccccc1n2-c1ccccc1 ; c1ccc(-c2nc(-c3ccccc3)nc(-c3cc(-c4c(-c5ccccc5)cccc4-c4ccccc4)ccc3-c3cccc4sc5c(ccc6c7ccccc7n(-c7ccccc7)c65)c34)n2)cc1 ; c1ccc(-c2nc(-c3ccccc3)nc(-c3cc(-c4ccccc4-c4ccccc4)ccc3-c3cccc4c3sc3ccc5c(c6ccccc6n5-c5ccccc5)c34)n2)cc1]

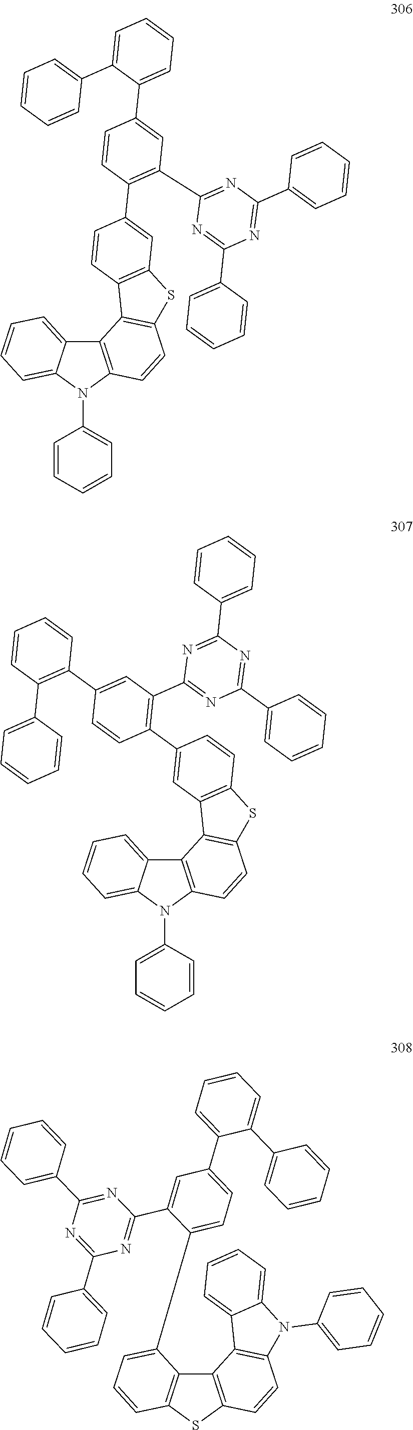 [SMILES: c1ccc(-c2nc(-c3ccccc3)nc(-c3cc(-c4ccccc4-c4ccccc4)ccc3-c3ccc4c(c3)sc3ccc5c(c6ccccc6n5-c5ccccc5)c34)n2)cc1 ; c1ccc(-c2nc(-c3ccccc3)nc(-c3cc(-c4ccccc4-c4ccccc4)ccc3-c3ccc4sc5ccc6c(c7ccccc7n6-c6ccccc6)c5c4c3)n2)cc1 ; c1ccc(-c2nc(-c3ccccc3)nc(-c3cc(-c4ccccc4-c4ccccc4)ccc3-c3cccc4sc5ccc6c(c7ccccc7n6-c6ccccc6)c5c34)n2)cc1]

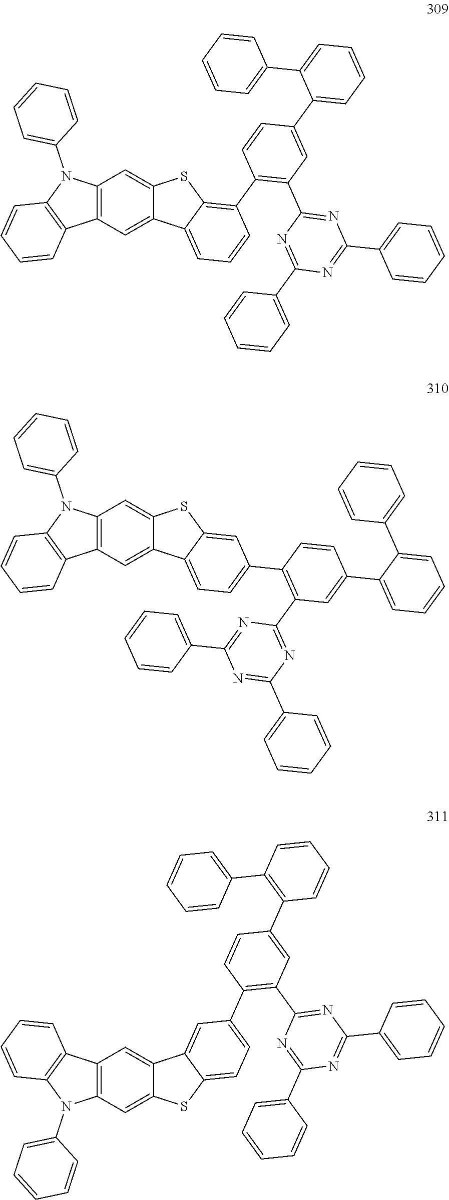 [SMILES: c1ccc(-c2nc(-c3ccccc3)nc(-c3cc(-c4ccccc4-c4ccccc4)ccc3-c3cccc4c3sc3cc5c(cc34)c3ccccc3n5-c3ccccc3)n2)cc1 ; c1ccc(-c2nc(-c3ccccc3)nc(-c3cc(-c4ccccc4-c4ccccc4)ccc3-c3ccc4c(c3)sc3cc5c(cc34)c3ccccc3n5-c3ccccc3)n2)cc1 ; c1ccc(-c2nc(-c3ccccc3)nc(-c3cc(-c4ccccc4-c4ccccc4)ccc3-c3ccc4sc5cc6c(cc5c4c3)c3ccccc3n6-c3ccccc3)n2)cc1]

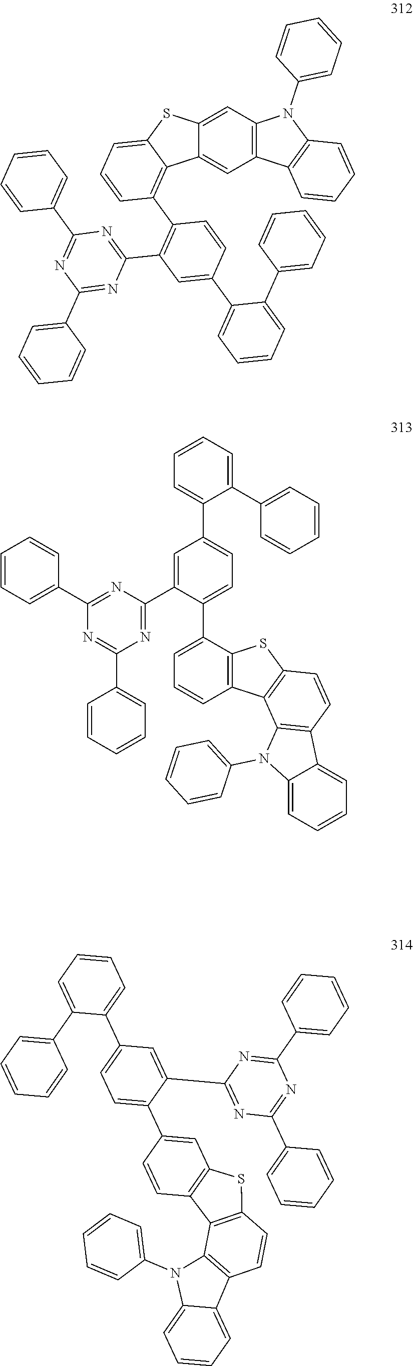 [SMILES: c1ccc(-c2nc(-c3ccccc3)nc(-c3cc(-c4ccccc4-c4ccccc4)ccc3-c3cccc4sc5cc6c(cc5c34)c3ccccc3n6-c3ccccc3)n2)cc1 ; c1ccc(-c2nc(-c3ccccc3)nc(-c3cc(-c4ccccc4-c4ccccc4)ccc3-c3cccc4c3sc3ccc5c6ccccc6n(-c6ccccc6)c5c34)n2)cc1 ; c1ccc(-c2nc(-c3ccccc3)nc(-c3cc(-c4ccccc4-c4ccccc4)ccc3-c3ccc4c(c3)sc3ccc5c6ccccc6n(-c6ccccc6)c5c34)n2)cc1]

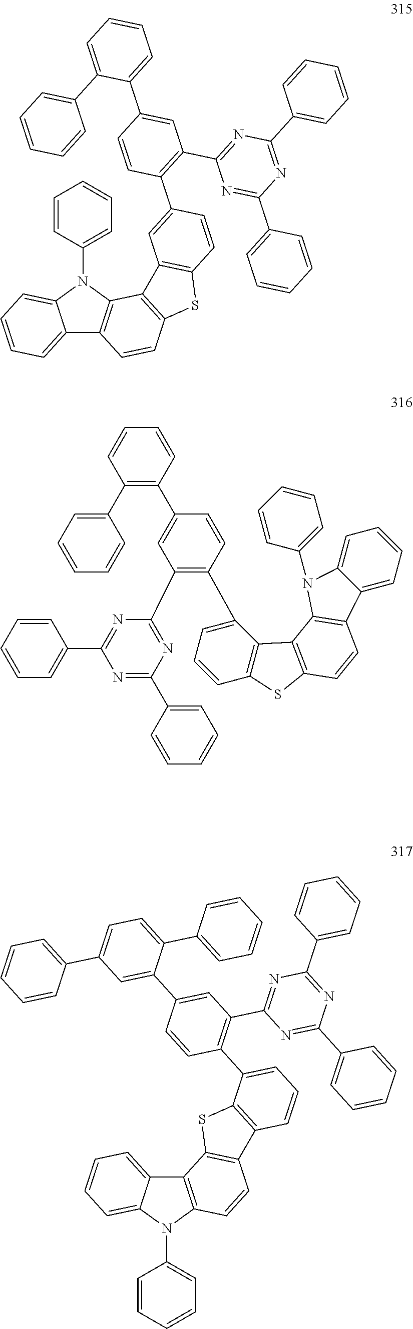 [SMILES: c1ccc(-c2nc(-c3ccccc3)nc(-c3cc(-c4ccccc4-c4ccccc4)ccc3-c3ccc4sc5ccc6c7ccccc7n(-c7ccccc7)c6c5c4c3)n2)cc1 ; c1ccc(-c2nc(-c3ccccc3)nc(-c3cc(-c4ccccc4-c4ccccc4)ccc3-c3cccc4sc5ccc6c7ccccc7n(-c7ccccc7)c6c5c34)n2)cc1 ; c1ccc(-c2ccc(-c3ccccc3)c(-c3ccc(-c4cccc5c4sc4c5ccc5c4c4ccccc4n5-c4ccccc4)c(-c4nc(-c5ccccc5)nc(-c5ccccc5)n4)c3)c2)cc1]

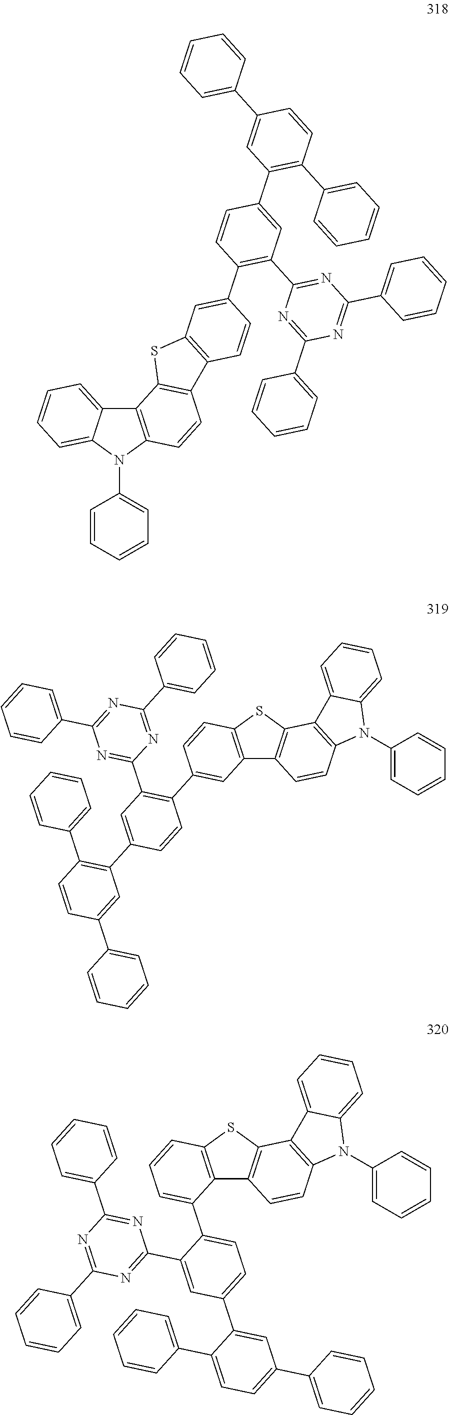 [SMILES: c1ccc(-c2ccc(-c3ccccc3)c(-c3ccc(-c4ccc5c(c4)sc4c5ccc5c4c4ccccc4n5-c4ccccc4)c(-c4nc(-c5ccccc5)nc(-c5ccccc5)n4)c3)c2)cc1 ; c1ccc(-c2ccc(-c3ccccc3)c(-c3ccc(-c4ccc5sc6c(ccc7c6c6ccccc6n7-c6ccccc6)c5c4)c(-c4nc(-c5ccccc5)nc(-c5ccccc5)n4)c3)c2)cc1 ; c1ccc(-c2ccc(-c3ccccc3)c(-c3ccc(-c4cccc5sc6c(ccc7c6c6ccccc6n7-c6ccccc6)c45)c(-c4nc(-c5ccccc5)nc(-c5ccccc5)n4)c3)c2)cc1]

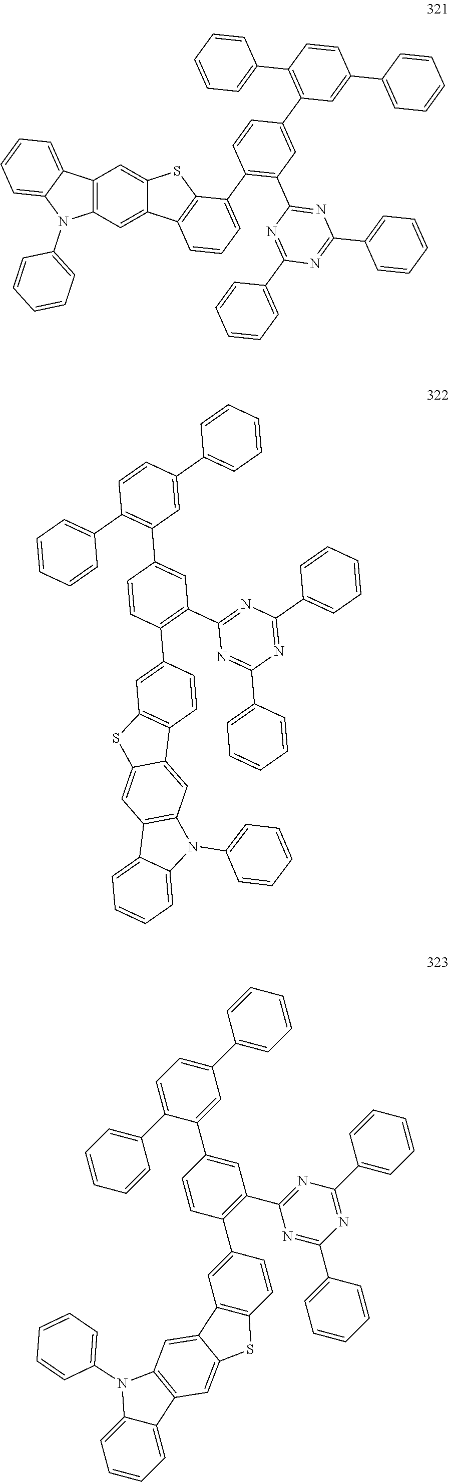 [SMILES: c1ccc(-c2ccc(-c3ccccc3)c(-c3ccc(-c4cccc5c4sc4cc6c7ccccc7n(-c7ccccc7)c6cc45)c(-c4nc(-c5ccccc5)nc(-c5ccccc5)n4)c3)c2)cc1 ; c1ccc(-c2ccc(-c3ccccc3)c(-c3ccc(-c4ccc5c(c4)sc4cc6c7ccccc7n(-c7ccccc7)c6cc45)c(-c4nc(-c5ccccc5)nc(-c5ccccc5)n4)c3)c2)cc1 ; c1ccc(-c2ccc(-c3ccccc3)c(-c3ccc(-c4ccc5sc6cc7c8ccccc8n(-c8ccccc8)c7cc6c5c4)c(-c4nc(-c5ccccc5)nc(-c5ccccc5)n4)c3)c2)cc1]

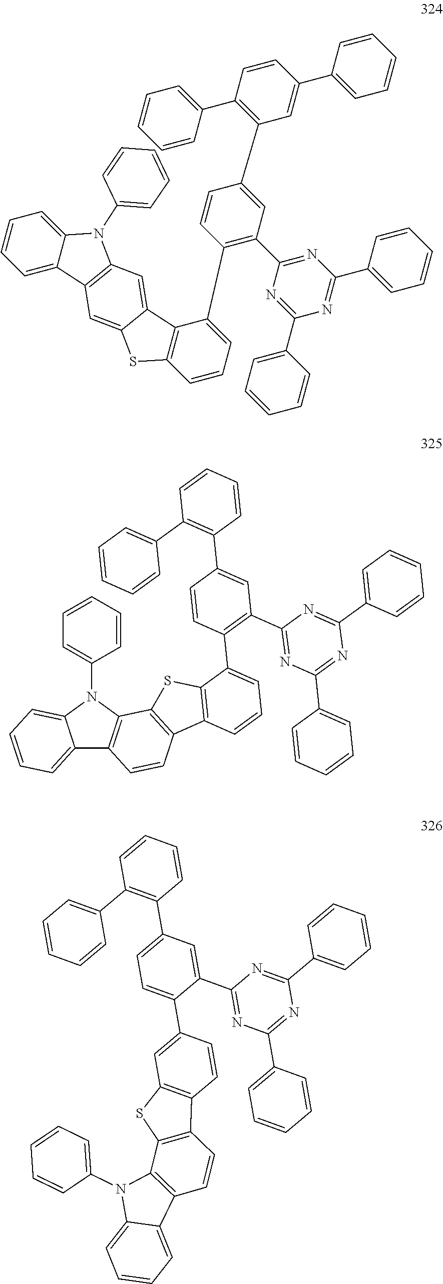 [SMILES: c1ccc(-c2ccc(-c3ccccc3)c(-c3ccc(-c4cccc5sc6cc7c8ccccc8n(-c8ccccc8)c7cc6c45)c(-c4nc(-c5ccccc5)nc(-c5ccccc5)n4)c3)c2)cc1 ; c1ccc(-c2nc(-c3ccccc3)nc(-c3cc(-c4ccccc4-c4ccccc4)ccc3-c3cccc4c3sc3c4ccc4c5ccccc5n(-c5ccccc5)c43)n2)cc1 ; c1ccc(-c2nc(-c3ccccc3)nc(-c3cc(-c4ccccc4-c4ccccc4)ccc3-c3ccc4c(c3)sc3c4ccc4c5ccccc5n(-c5ccccc5)c43)n2)cc1]

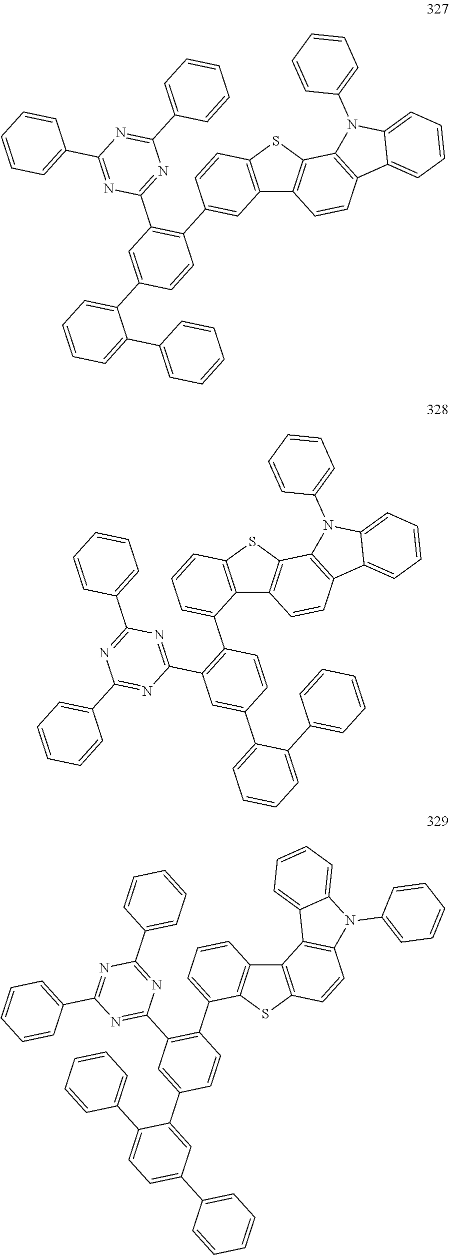 [SMILES: c1ccc(-c2nc(-c3ccccc3)nc(-c3cc(-c4ccccc4-c4ccccc4)ccc3-c3ccc4sc5c(ccc6c7ccccc7n(-c7ccccc7)c65)c4c3)n2)cc1 ; c1ccc(-c2nc(-c3ccccc3)nc(-c3cc(-c4ccccc4-c4ccccc4)ccc3-c3cccc4sc5c(ccc6c7ccccc7n(-c7ccccc7)c65)c34)n2)cc1 ; c1ccc(-c2ccc(-c3ccccc3)c(-c3ccc(-c4cccc5c4sc4ccc6c(c7ccccc7n6-c6ccccc6)c45)c(-c4nc(-c5ccccc5)nc(-c5ccccc5)n4)c3)c2)cc1]

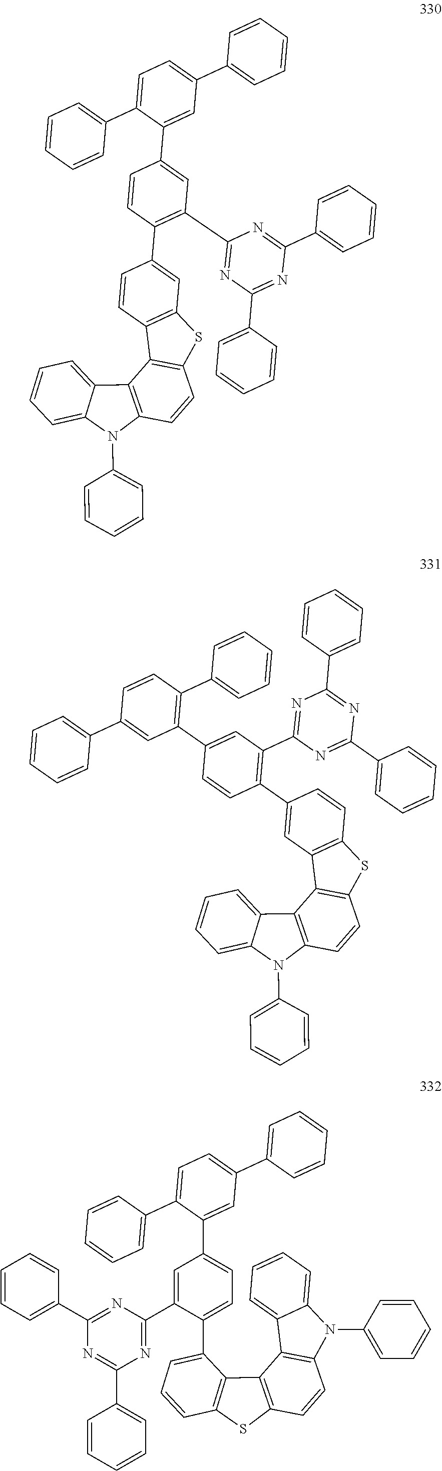 [SMILES: c1ccc(-c2ccc(-c3ccccc3)c(-c3ccc(-c4ccc5c(c4)sc4ccc6c(c7ccccc7n6-c6ccccc6)c45)c(-c4nc(-c5ccccc5)nc(-c5ccccc5)n4)c3)c2)cc1 ; c1ccc(-c2ccc(-c3ccccc3)c(-c3ccc(-c4ccc5sc6ccc7c(c8ccccc8n7-c7ccccc7)c6c5c4)c(-c4nc(-c5ccccc5)nc(-c5ccccc5)n4)c3)c2)cc1 ; c1ccc(-c2ccc(-c3ccccc3)c(-c3ccc(-c4cccc5sc6ccc7c(c8ccccc8n7-c7ccccc7)c6c45)c(-c4nc(-c5ccccc5)nc(-c5ccccc5)n4)c3)c2)cc1]

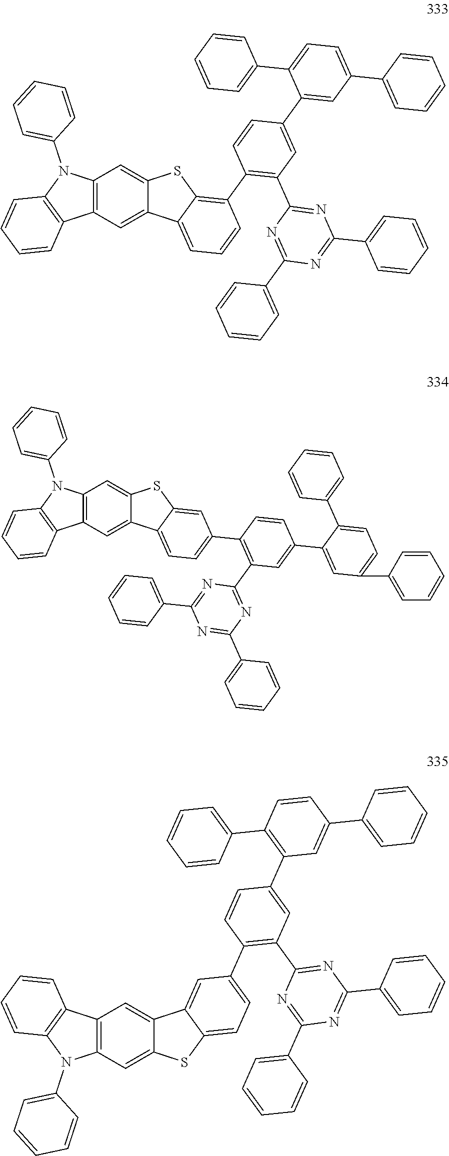 [SMILES: c1ccc(-c2ccc(-c3ccccc3)c(-c3ccc(-c4cccc5c4sc4cc6c(cc45)c4ccccc4n6-c4ccccc4)c(-c4nc(-c5ccccc5)nc(-c5ccccc5)n4)c3)c2)cc1 ; c1ccc(-c2ccc(-c3ccccc3)c(-c3ccc(-c4ccc5c(c4)sc4cc6c(cc45)c4ccccc4n6-c4ccccc4)c(-c4nc(-c5ccccc5)nc(-c5ccccc5)n4)c3)c2)cc1 ; c1ccc(-c2ccc(-c3ccccc3)c(-c3ccc(-c4ccc5sc6cc7c(cc6c5c4)c4ccccc4n7-c4ccccc4)c(-c4nc(-c5ccccc5)nc(-c5ccccc5)n4)c3)c2)cc1]

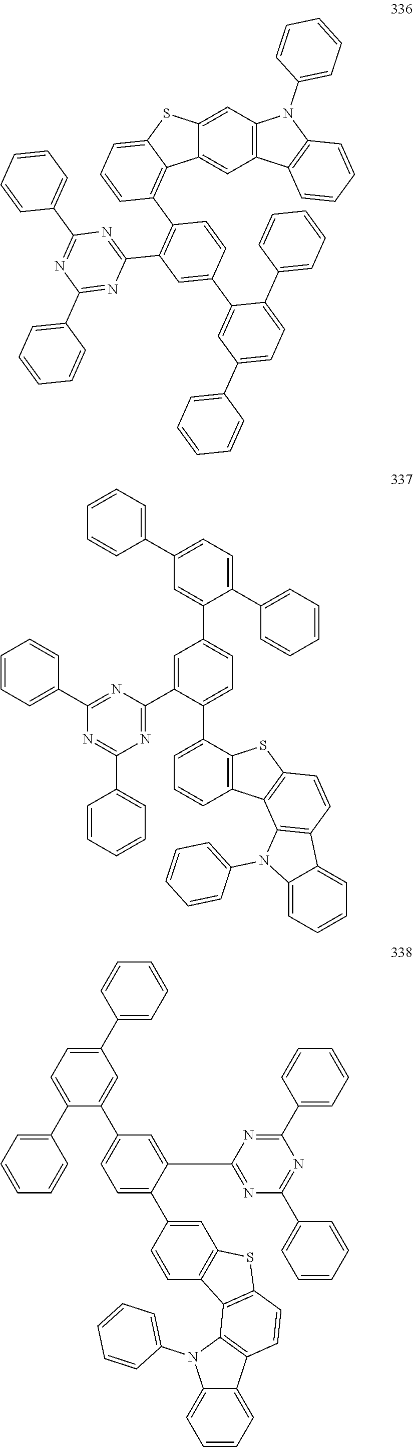 [SMILES: c1ccc(-c2ccc(-c3ccccc3)c(-c3ccc(-c4cccc5sc6cc7c(cc6c45)c4ccccc4n7-c4ccccc4)c(-c4nc(-c5ccccc5)nc(-c5ccccc5)n4)c3)c2)cc1 ; c1ccc(-c2ccc(-c3ccccc3)c(-c3ccc(-c4cccc5c4sc4ccc6c7ccccc7n(-c7ccccc7)c6c45)c(-c4nc(-c5ccccc5)nc(-c5ccccc5)n4)c3)c2)cc1 ; c1ccc(-c2ccc(-c3ccccc3)c(-c3ccc(-c4ccc5c(c4)sc4ccc6c7ccccc7n(-c7ccccc7)c6c45)c(-c4nc(-c5ccccc5)nc(-c5ccccc5)n4)c3)c2)cc1]

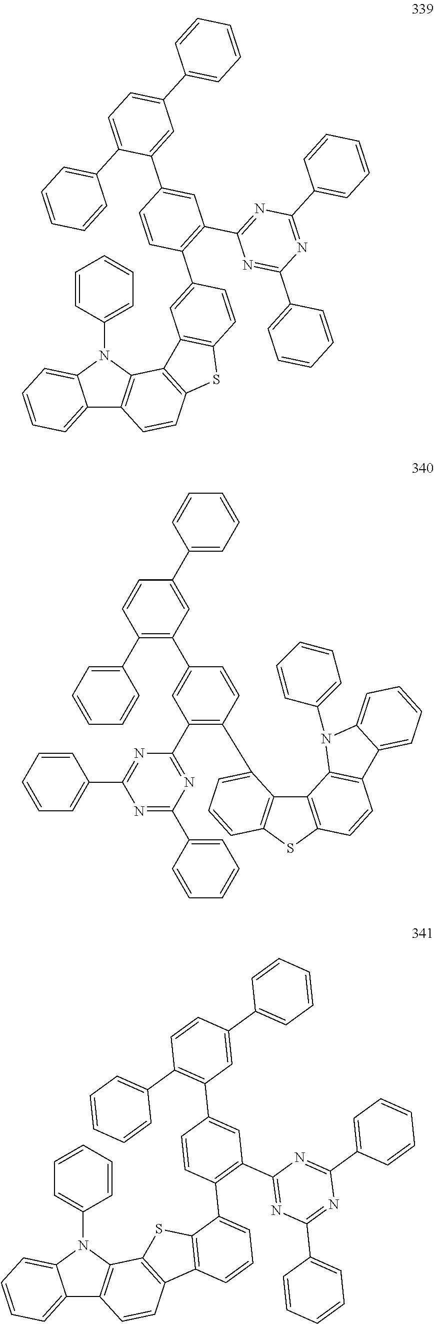 [SMILES: c1ccc(-c2ccc(-c3ccccc3)c(-c3ccc(-c4ccc5sc6ccc7c8ccccc8n(-c8ccccc8)c7c6c5c4)c(-c4nc(-c5ccccc5)nc(-c5ccccc5)n4)c3)c2)cc1 ; c1ccc(-c2ccc(-c3ccccc3)c(-c3ccc(-c4cccc5sc6ccc7c8ccccc8n(-c8ccccc8)c7c6c45)c(-c4nc(-c5ccccc5)nc(-c5ccccc5)n4)c3)c2)cc1 ; c1ccc(-c2ccc(-c3ccccc3)c(-c3ccc(-c4cccc5c4sc4c5ccc5c6ccccc6n(-c6ccccc6)c54)c(-c4nc(-c5ccccc5)nc(-c5ccccc5)n4)c3)c2)cc1]

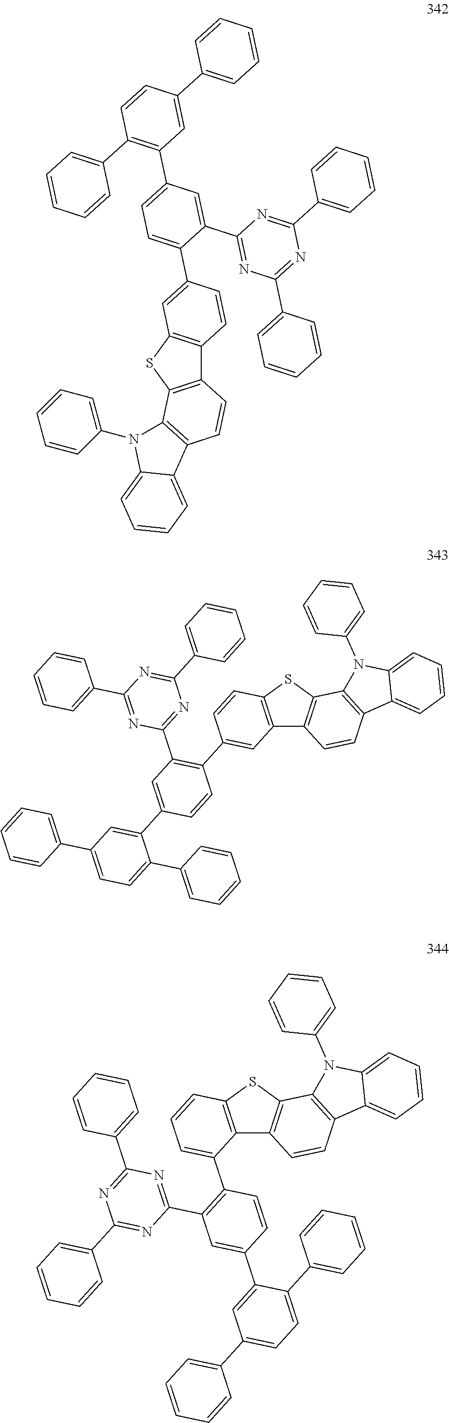 [SMILES: c1ccc(-c2ccc(-c3ccccc3)c(-c3ccc(-c4ccc5c(c4)sc4c5ccc5c6ccccc6n(-c6ccccc6)c54)c(-c4nc(-c5ccccc5)nc(-c5ccccc5)n4)c3)c2)cc1 ; c1ccc(-c2ccc(-c3ccccc3)c(-c3ccc(-c4ccc5sc6c(ccc7c8ccccc8n(-c8ccccc8)c76)c5c4)c(-c4nc(-c5ccccc5)nc(-c5ccccc5)n4)c3)c2)cc1 ; c1ccc(-c2ccc(-c3ccccc3)c(-c3ccc(-c4cccc5sc6c(ccc7c8ccccc8n(-c8ccccc8)c76)c45)c(-c4nc(-c5ccccc5)nc(-c5ccccc5)n4)c3)c2)cc1]

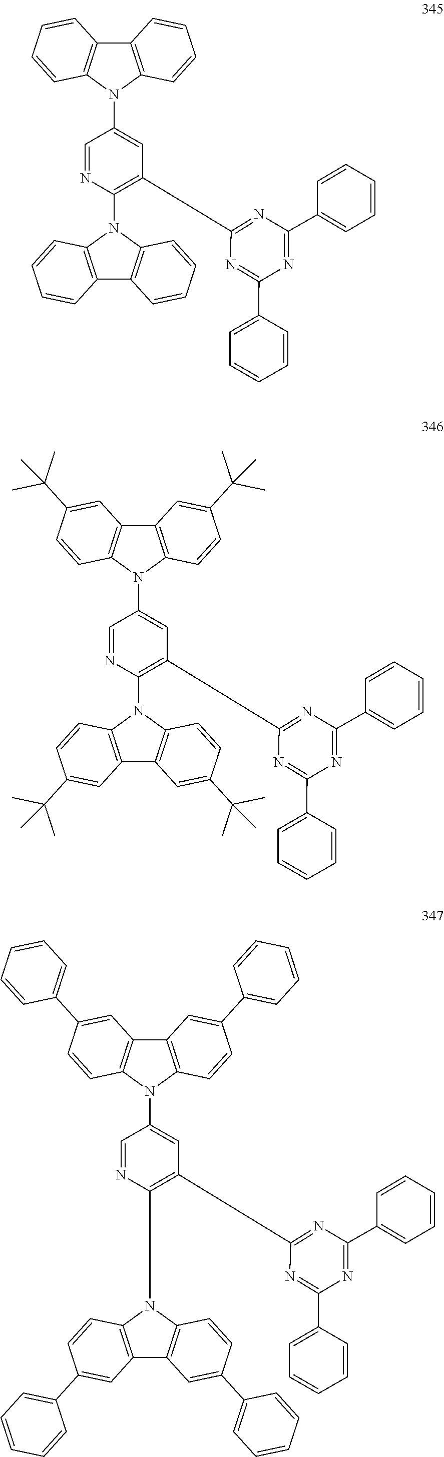 [SMILES: c1ccc(-c2nc(-c3ccccc3)nc(-c3cc(-n4c5ccccc5c5ccccc54)cnc3-n3c4ccccc4c4ccccc43)n2)cc1 ; CC(C)(C)c1ccc2c(c1)c1cc(C(C)(C)C)ccc1n2-c1cnc(-n2c3ccc(C(C)(C)C)cc3c3cc(C(C)(C)C)ccc32)c(-c2nc(-c3ccccc3)nc(-c3ccccc3)n2)c1 ; c1ccc(-c2ccc3c(c2)c2cc(-c4ccccc4)ccc2n3-c2cnc(-n3c4ccc(-c5ccccc5)cc4c4cc(-c5ccccc5)ccc43)c(-c3nc(-c4ccccc4)nc(-c4ccccc4)n3)c2)cc1]

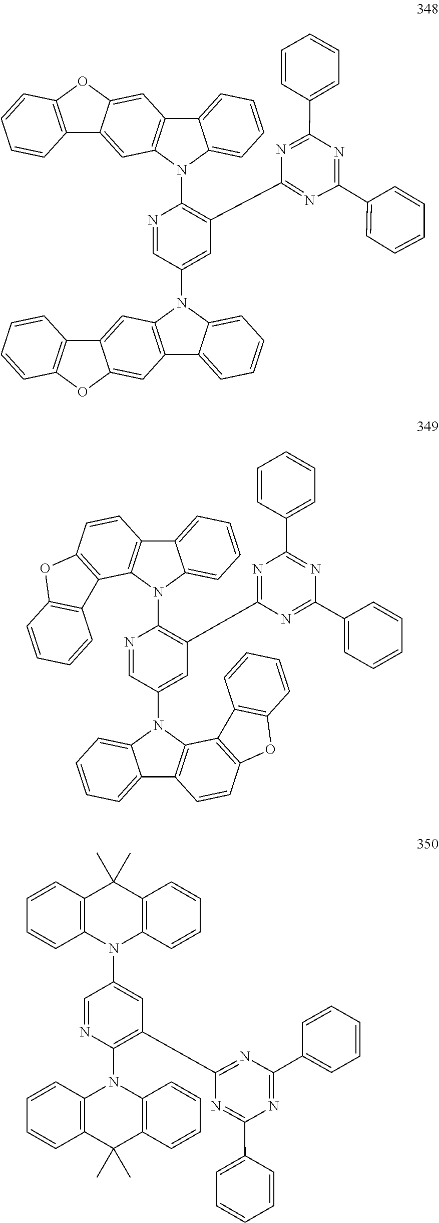 [SMILES: c1ccc(-c2nc(-c3ccccc3)nc(-c3cc(-n4c5ccccc5c5cc6oc7ccccc7c6cc54)cnc3-n3c4ccccc4c4cc5oc6ccccc6c5cc43)n2)cc1 ; c1ccc(-c2nc(-c3ccccc3)nc(-c3cc(-n4c5ccccc5c5ccc6oc7ccccc7c6c54)cnc3-n3c4ccccc4c4ccc5oc6ccccc6c5c43)n2)cc1 ; CC1(C)c2ccccc2N(c2cnc(N3c4ccccc4C(C)(C)c4ccccc43)c(-c3nc(-c4ccccc4)nc(-c4ccccc4)n3)c2)c2ccccc21]

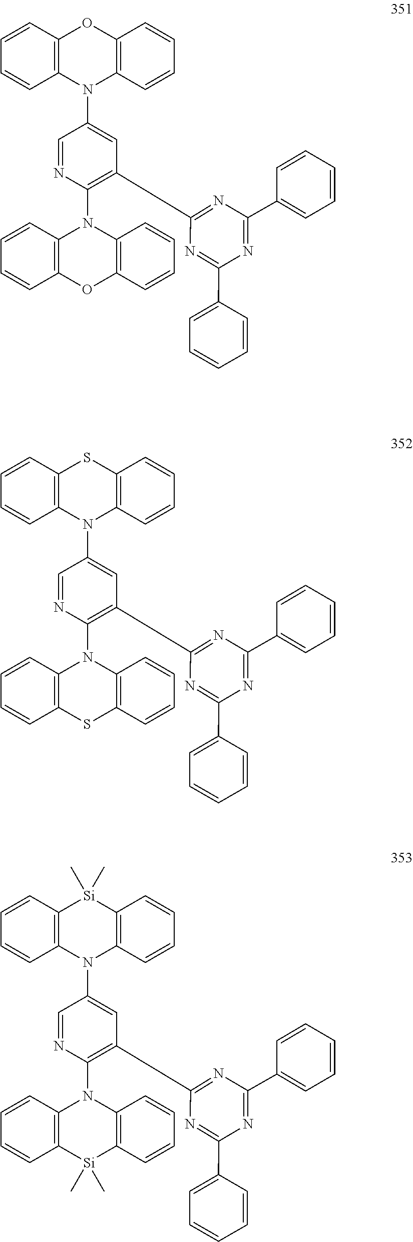 [SMILES: c1ccc(-c2nc(-c3ccccc3)nc(-c3cc(N4c5ccccc5Oc5ccccc54)cnc3N3c4ccccc4Oc4ccccc43)n2)cc1 ; c1ccc(-c2nc(-c3ccccc3)nc(-c3cc(N4c5ccccc5Sc5ccccc54)cnc3N3c4ccccc4Sc4ccccc43)n2)cc1 ; C[Si]1(C)c2ccccc2N(c2cnc(N3c4ccccc4[Si](C)(C)c4ccccc43)c(-c3nc(-c4ccccc4)nc(-c4ccccc4)n3)c2)c2ccccc21]

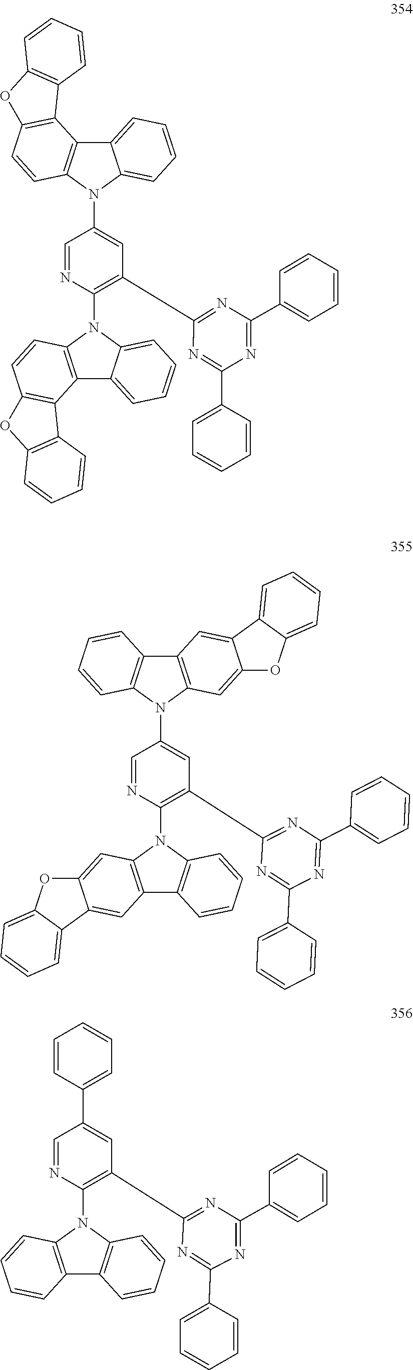 [SMILES: c1ccc(-c2nc(-c3ccccc3)nc(-c3cc(-n4c5ccccc5c5c6c(ccc54)oc4ccccc46)cnc3-n3c4ccccc4c4c5c(ccc43)oc3ccccc35)n2)cc1 ; c1ccc(-c2nc(-c3ccccc3)nc(-c3cc(-n4c5ccccc5c5cc6c(cc54)oc4ccccc46)cnc3-n3c4ccccc4c4cc5c(cc43)oc3ccccc35)n2)cc1 ; c1ccc(-c2cnc(-n3c4ccccc4c4ccccc43)c(-c3nc(-c4ccccc4)nc(-c4ccccc4)n3)c2)cc1]

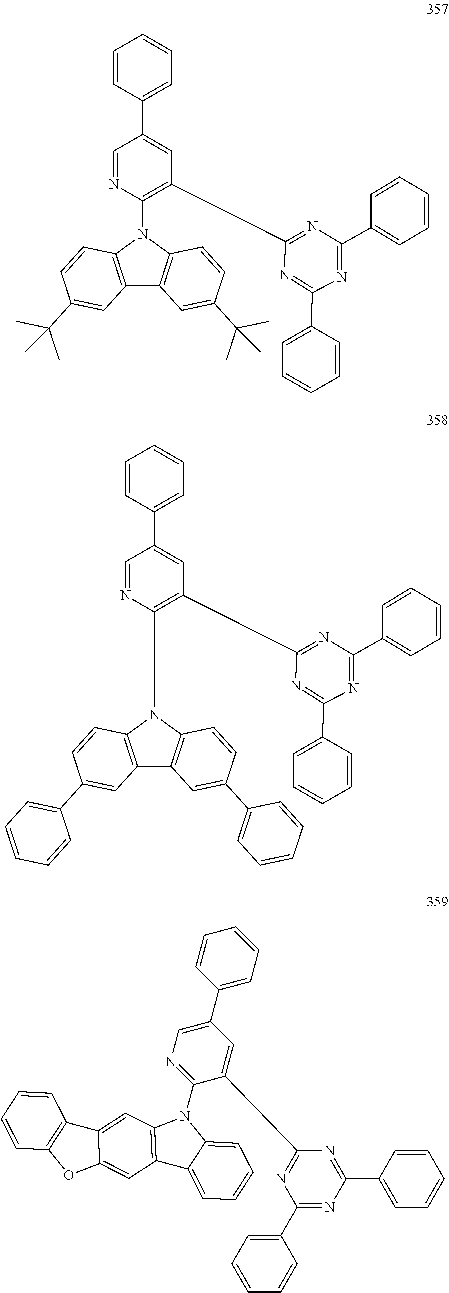 [SMILES: CC(C)(C)c1ccc2c(c1)c1cc(C(C)(C)C)ccc1n2-c1ncc(-c2ccccc2)cc1-c1nc(-c2ccccc2)nc(-c2ccccc2)n1 ; c1ccc(-c2cnc(-n3c4ccc(-c5ccccc5)cc4c4cc(-c5ccccc5)ccc43)c(-c3nc(-c4ccccc4)nc(-c4ccccc4)n3)c2)cc1 ; c1ccc(-c2cnc(-n3c4ccccc4c4cc5oc6ccccc6c5cc43)c(-c3nc(-c4ccccc4)nc(-c4ccccc4)n3)c2)cc1]

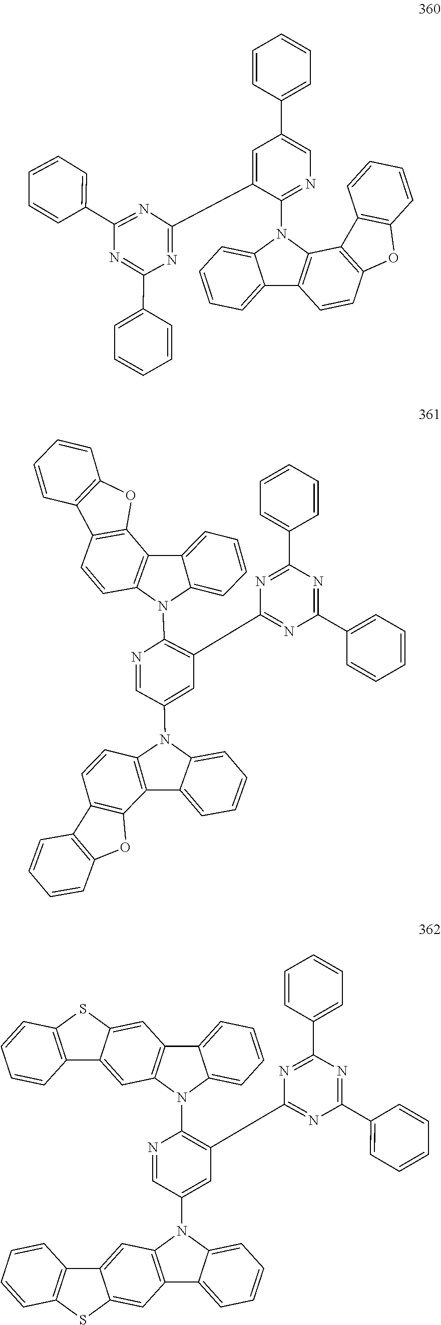 [SMILES: c1ccc(-c2cnc(-n3c4ccccc4c4ccc5oc6ccccc6c5c43)c(-c3nc(-c4ccccc4)nc(-c4ccccc4)n3)c2)cc1 ; c1ccc(-c2nc(-c3ccccc3)nc(-c3cc(-n4c5ccccc5c5c6oc7ccccc7c6ccc54)cnc3-n3c4ccccc4c4c5oc6ccccc6c5ccc43)n2)cc1 ; c1ccc(-c2nc(-c3ccccc3)nc(-c3cc(-n4c5ccccc5c5cc6sc7ccccc7c6cc54)cnc3-n3c4ccccc4c4cc5sc6ccccc6c5cc43)n2)cc1]

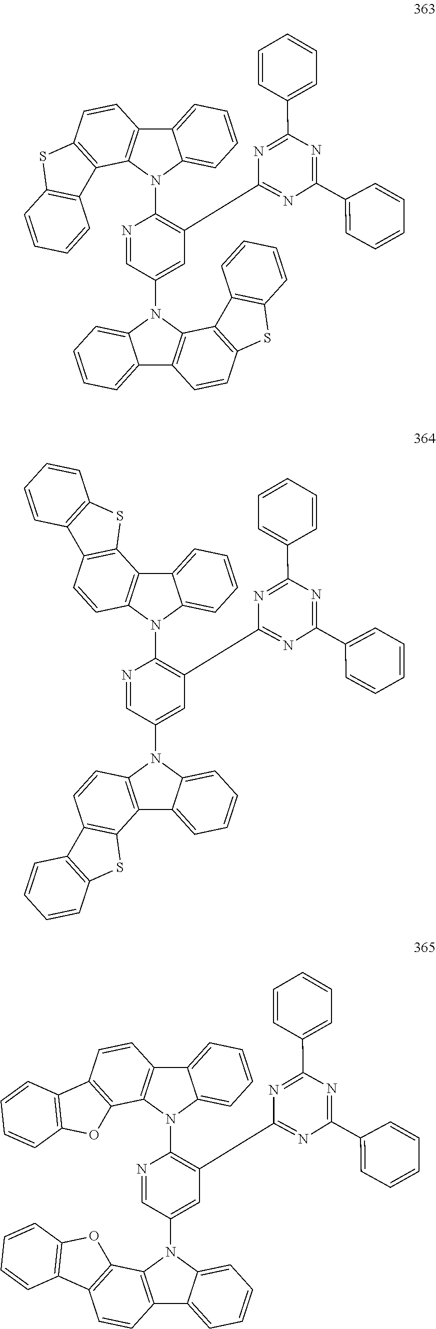 [SMILES: c1ccc(-c2nc(-c3ccccc3)nc(-c3cc(-n4c5ccccc5c5ccc6sc7ccccc7c6c54)cnc3-n3c4ccccc4c4ccc5sc6ccccc6c5c43)n2)cc1 ; c1ccc(-c2nc(-c3ccccc3)nc(-c3cc(-n4c5ccccc5c5c6sc7ccccc7c6ccc54)cnc3-n3c4ccccc4c4c5sc6ccccc6c5ccc43)n2)cc1 ; c1ccc(-c2nc(-c3ccccc3)nc(-c3cc(-n4c5ccccc5c5ccc6c7ccccc7oc6c54)cnc3-n3c4ccccc4c4ccc5c6ccccc6oc5c43)n2)cc1]

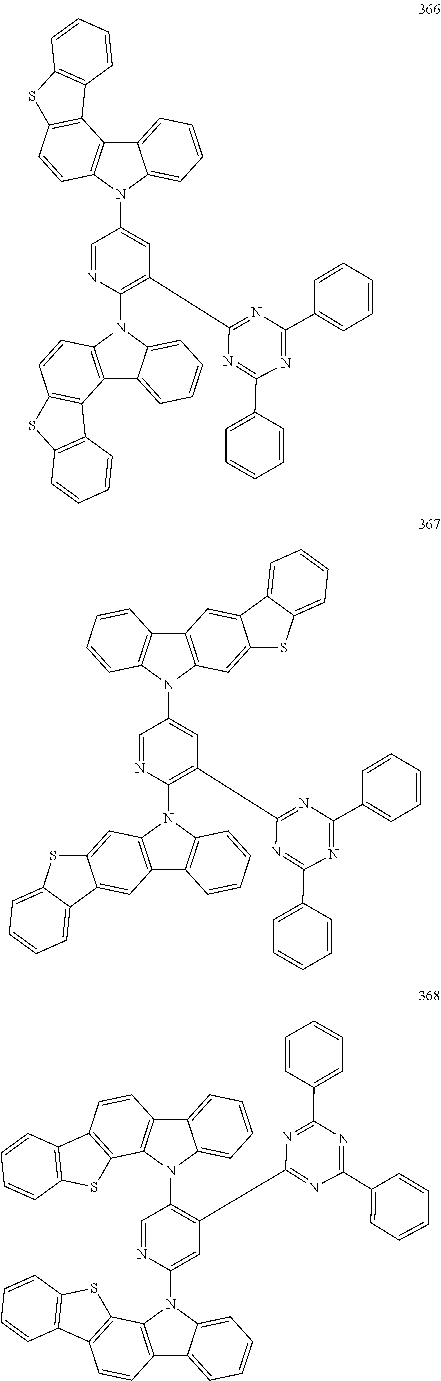 [SMILES: c1ccc(-c2nc(-c3ccccc3)nc(-c3cc(-n4c5ccccc5c5c6c(ccc54)sc4ccccc46)cnc3-n3c4ccccc4c4c5c(ccc43)sc3ccccc35)n2)cc1 ; c1ccc(-c2nc(-c3ccccc3)nc(-c3cc(-n4c5ccccc5c5cc6c(cc54)sc4ccccc46)cnc3-n3c4ccccc4c4cc5c(cc43)sc3ccccc35)n2)cc1 ; c1ccc(-c2nc(-c3ccccc3)nc(-c3cc(-n4c5ccccc5c5ccc6c7ccccc7sc6c54)ncc3-n3c4ccccc4c4ccc5c6ccccc6sc5c43)n2)cc1]

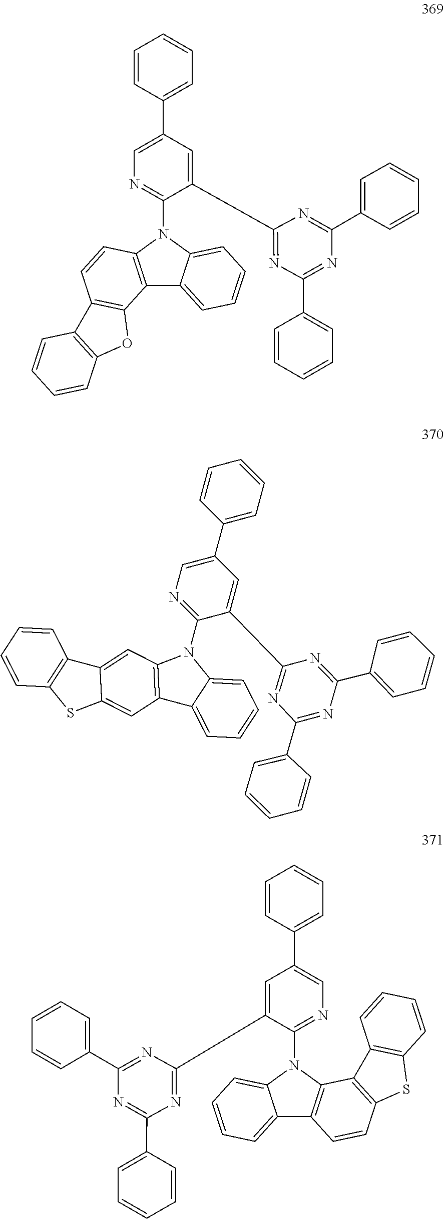 [SMILES: c1ccc(-c2cnc(-n3c4ccccc4c4c5oc6ccccc6c5ccc43)c(-c3nc(-c4ccccc4)nc(-c4ccccc4)n3)c2)cc1 ; c1ccc(-c2cnc(-n3c4ccccc4c4cc5sc6ccccc6c5cc43)c(-c3nc(-c4ccccc4)nc(-c4ccccc4)n3)c2)cc1 ; c1ccc(-c2cnc(-n3c4ccccc4c4ccc5sc6ccccc6c5c43)c(-c3nc(-c4ccccc4)nc(-c4ccccc4)n3)c2)cc1]

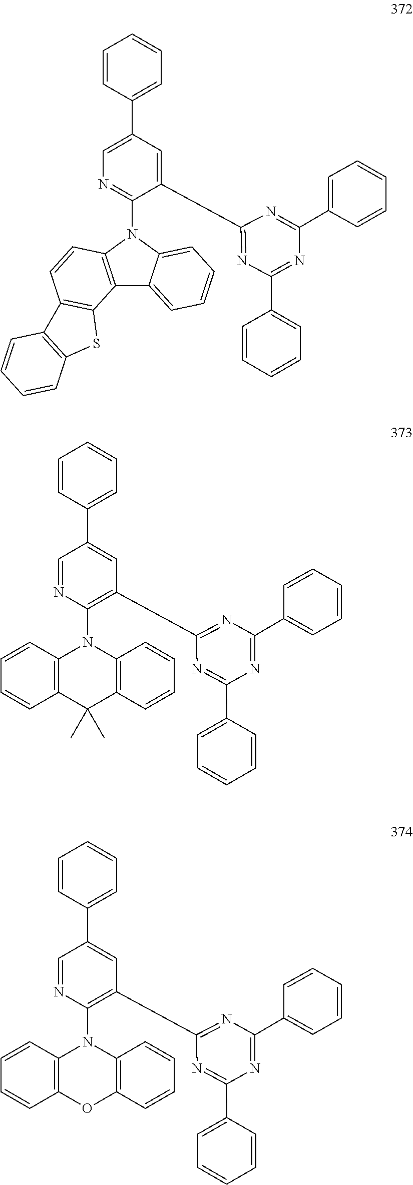 [SMILES: c1ccc(-c2cnc(-n3c4ccccc4c4c5sc6ccccc6c5ccc43)c(-c3nc(-c4ccccc4)nc(-c4ccccc4)n3)c2)cc1 ; CC1(C)c2ccccc2N(c2ncc(-c3ccccc3)cc2-c2nc(-c3ccccc3)nc(-c3ccccc3)n2)c2ccccc21 ; c1ccc(-c2cnc(N3c4ccccc4Oc4ccccc43)c(-c3nc(-c4ccccc4)nc(-c4ccccc4)n3)c2)cc1]

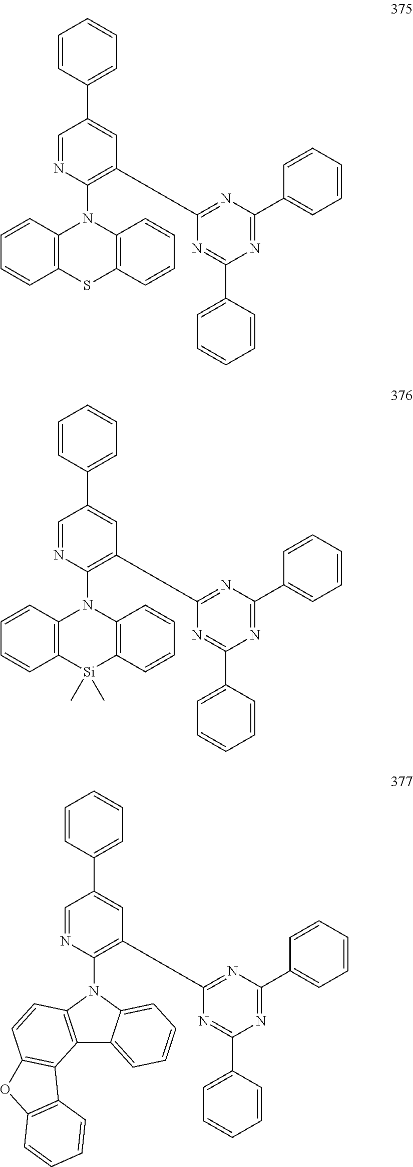 [SMILES: c1ccc(-c2cnc(N3c4ccccc4Sc4ccccc43)c(-c3nc(-c4ccccc4)nc(-c4ccccc4)n3)c2)cc1 ; C[Si]1(C)c2ccccc2N(c2ncc(-c3ccccc3)cc2-c2nc(-c3ccccc3)nc(-c3ccccc3)n2)c2ccccc21 ; c1ccc(-c2cnc(-n3c4ccccc4c4c5c(ccc43)oc3ccccc35)c(-c3nc(-c4ccccc4)nc(-c4ccccc4)n3)c2)cc1]

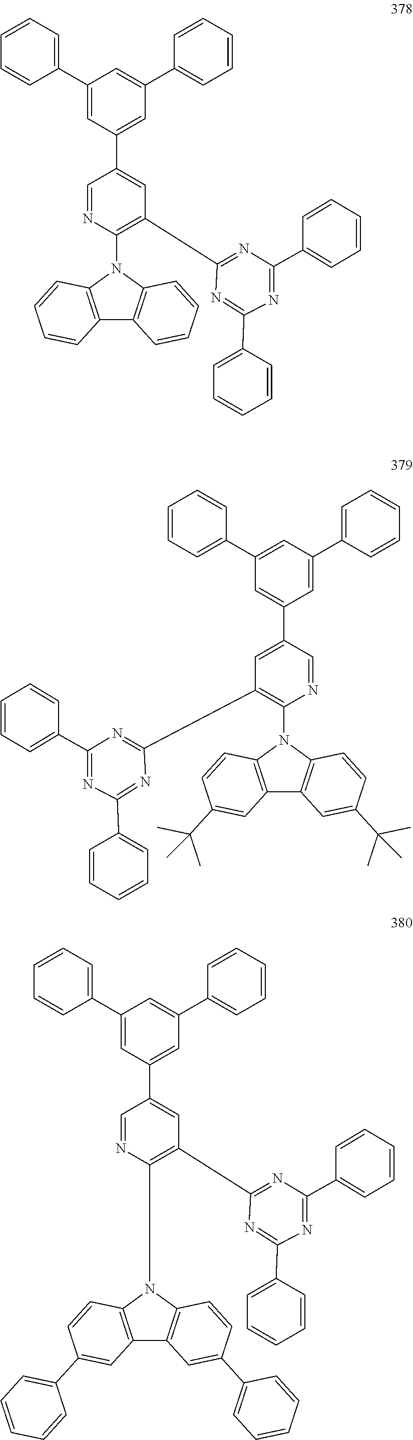 [SMILES: c1ccc(-c2cc(-c3ccccc3)cc(-c3cnc(-n4c5ccccc5c5ccccc54)c(-c4nc(-c5ccccc5)nc(-c5ccccc5)n4)c3)c2)cc1 ; CC(C)(C)c1ccc2c(c1)c1cc(C(C)(C)C)ccc1n2-c1ncc(-c2cc(-c3ccccc3)cc(-c3ccccc3)c2)cc1-c1nc(-c2ccccc2)nc(-c2ccccc2)n1 ; c1ccc(-c2cc(-c3ccccc3)cc(-c3cnc(-n4c5ccc(-c6ccccc6)cc5c5cc(-c6ccccc6)ccc54)c(-c4nc(-c5ccccc5)nc(-c5ccccc5)n4)c3)c2)cc1]

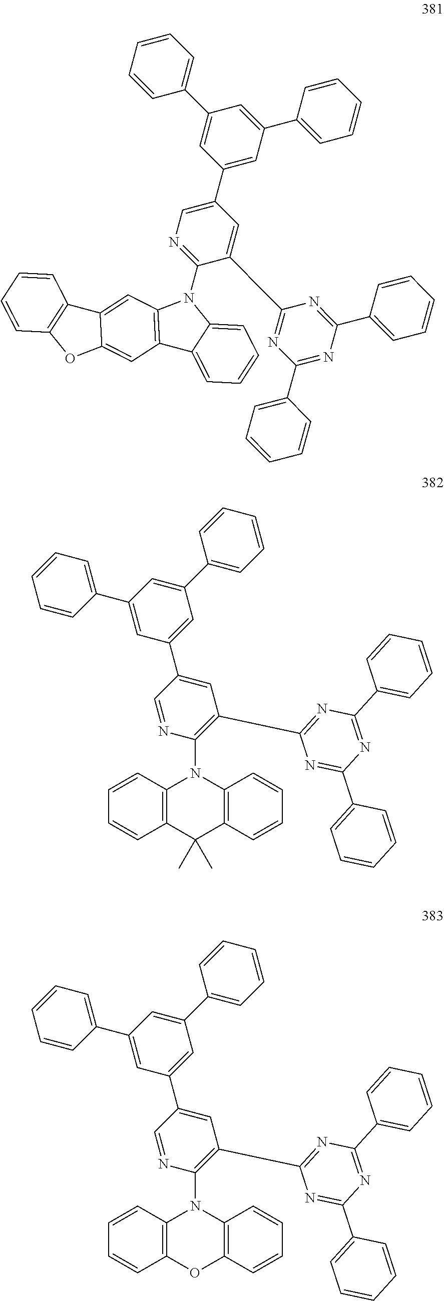 [SMILES: c1ccc(-c2cc(-c3ccccc3)cc(-c3cnc(-n4c5ccccc5c5cc6oc7ccccc7c6cc54)c(-c4nc(-c5ccccc5)nc(-c5ccccc5)n4)c3)c2)cc1 ; CC1(C)c2ccccc2N(c2ncc(-c3cc(-c4ccccc4)cc(-c4ccccc4)c3)cc2-c2nc(-c3ccccc3)nc(-c3ccccc3)n2)c2ccccc21 ; c1ccc(-c2cc(-c3ccccc3)cc(-c3cnc(N4c5ccccc5Oc5ccccc54)c(-c4nc(-c5ccccc5)nc(-c5ccccc5)n4)c3)c2)cc1]

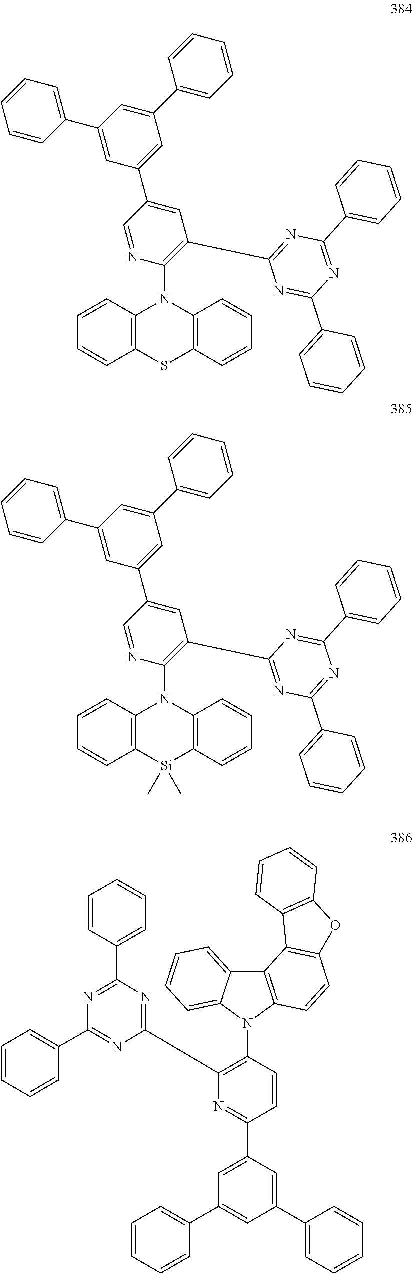 [SMILES: c1ccc(-c2cc(-c3ccccc3)cc(-c3cnc(N4c5ccccc5Sc5ccccc54)c(-c4nc(-c5ccccc5)nc(-c5ccccc5)n4)c3)c2)cc1 ; C[Si]1(C)c2ccccc2N(c2ncc(-c3cc(-c4ccccc4)cc(-c4ccccc4)c3)cc2-c2nc(-c3ccccc3)nc(-c3ccccc3)n2)c2ccccc21 ; c1ccc(-c2cc(-c3ccccc3)cc(-c3ccc(-n4c5ccccc5c5c6c(ccc54)oc4ccccc46)c(-c4nc(-c5ccccc5)nc(-c5ccccc5)n4)n3)c2)cc1]

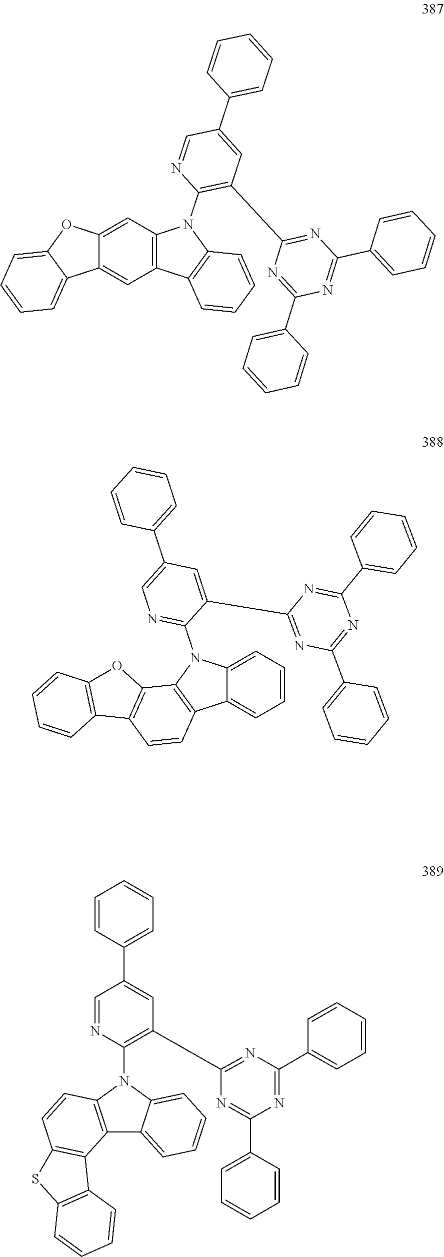 [SMILES: c1ccc(-c2cnc(-n3c4ccccc4c4cc5c(cc43)oc3ccccc35)c(-c3nc(-c4ccccc4)nc(-c4ccccc4)n3)c2)cc1 ; c1ccc(-c2cnc(-n3c4ccccc4c4ccc5c6ccccc6oc5c43)c(-c3nc(-c4ccccc4)nc(-c4ccccc4)n3)c2)cc1 ; c1ccc(-c2cnc(-n3c4ccccc4c4c5c(ccc43)sc3ccccc35)c(-c3nc(-c4ccccc4)nc(-c4ccccc4)n3)c2)cc1]

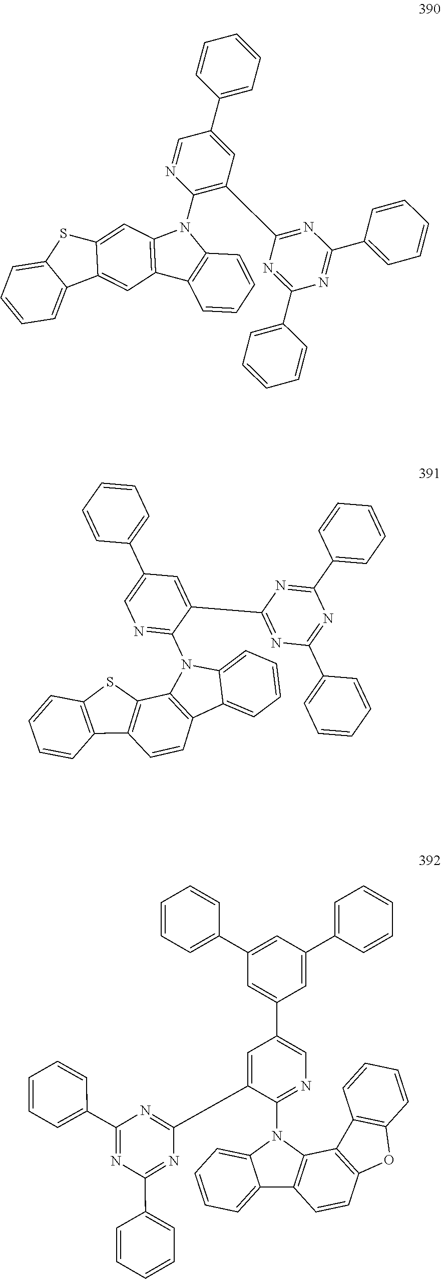 [SMILES: c1ccc(-c2cnc(-n3c4ccccc4c4cc5c(cc43)sc3ccccc35)c(-c3nc(-c4ccccc4)nc(-c4ccccc4)n3)c2)cc1 ; c1ccc(-c2cnc(-n3c4ccccc4c4ccc5c6ccccc6sc5c43)c(-c3nc(-c4ccccc4)nc(-c4ccccc4)n3)c2)cc1 ; c1ccc(-c2cc(-c3ccccc3)cc(-c3cnc(-n4c5ccccc5c5ccc6oc7ccccc7c6c54)c(-c4nc(-c5ccccc5)nc(-c5ccccc5)n4)c3)c2)cc1]

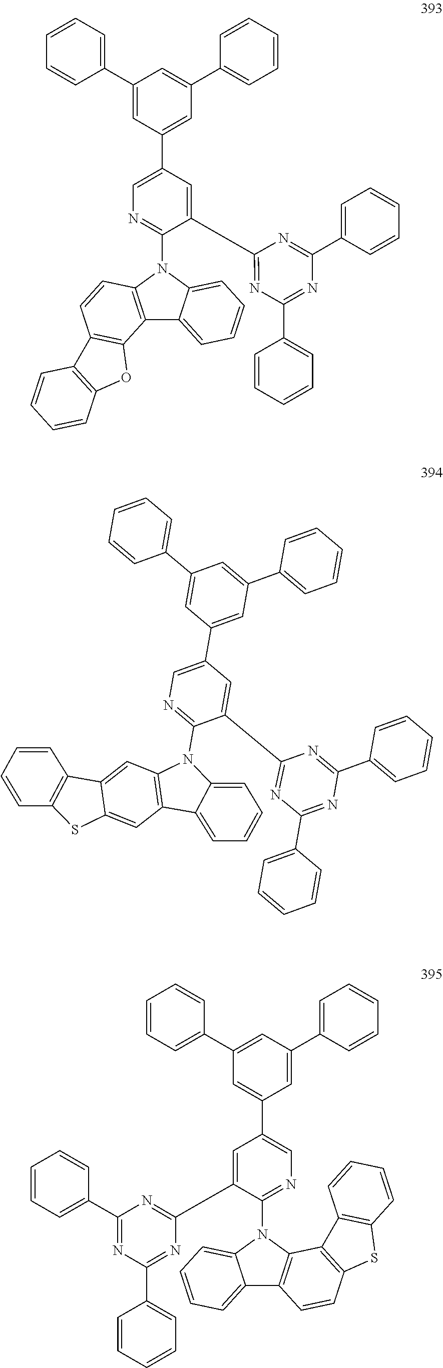 [SMILES: c1ccc(-c2cc(-c3ccccc3)cc(-c3cnc(-n4c5ccccc5c5c6oc7ccccc7c6ccc54)c(-c4nc(-c5ccccc5)nc(-c5ccccc5)n4)c3)c2)cc1 ; c1ccc(-c2cc(-c3ccccc3)cc(-c3cnc(-n4c5ccccc5c5cc6sc7ccccc7c6cc54)c(-c4nc(-c5ccccc5)nc(-c5ccccc5)n4)c3)c2)cc1 ; c1ccc(-c2cc(-c3ccccc3)cc(-c3cnc(-n4c5ccccc5c5ccc6sc7ccccc7c6c54)c(-c4nc(-c5ccccc5)nc(-c5ccccc5)n4)c3)c2)cc1]

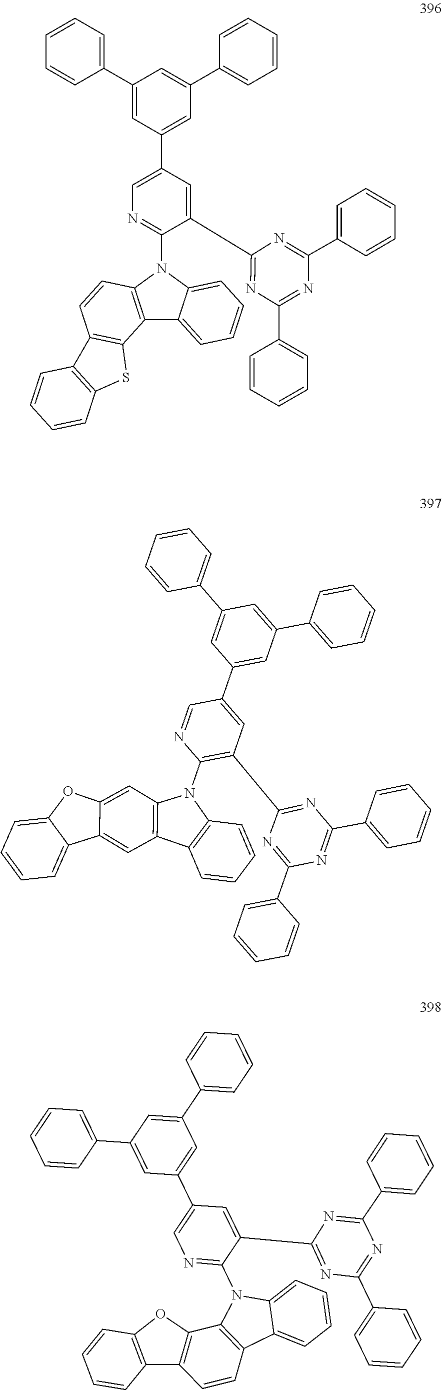 [SMILES: c1ccc(-c2cc(-c3ccccc3)cc(-c3cnc(-n4c5ccccc5c5c6sc7ccccc7c6ccc54)c(-c4nc(-c5ccccc5)nc(-c5ccccc5)n4)c3)c2)cc1 ; c1ccc(-c2cc(-c3ccccc3)cc(-c3cnc(-n4c5ccccc5c5cc6c(cc54)oc4ccccc46)c(-c4nc(-c5ccccc5)nc(-c5ccccc5)n4)c3)c2)cc1 ; c1ccc(-c2cc(-c3ccccc3)cc(-c3cnc(-n4c5ccccc5c5ccc6c7ccccc7oc6c54)c(-c4nc(-c5ccccc5)nc(-c5ccccc5)n4)c3)c2)cc1]

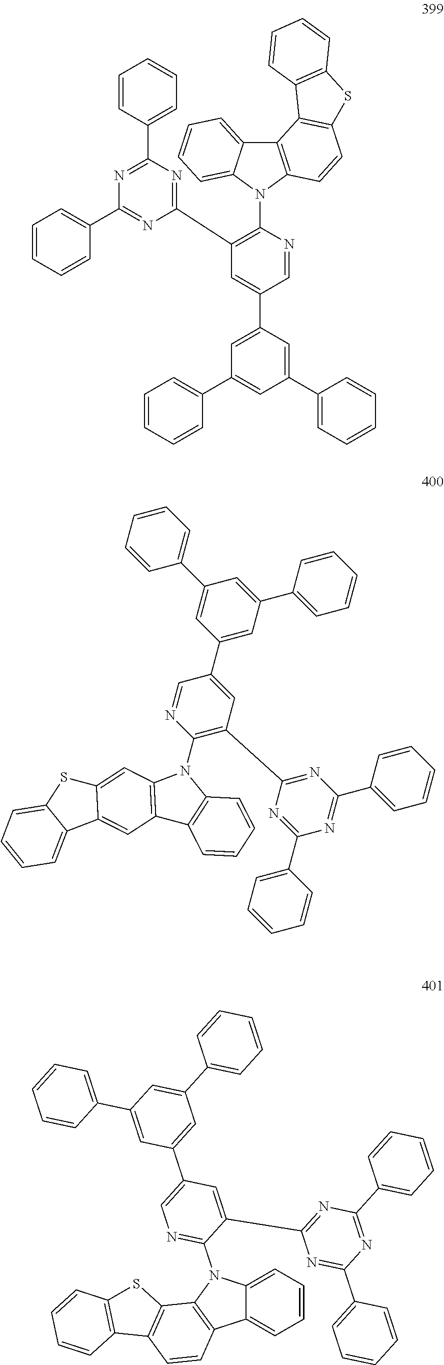 [SMILES: c1ccc(-c2cc(-c3ccccc3)cc(-c3cnc(-n4c5ccccc5c5c6c(ccc54)sc4ccccc46)c(-c4nc(-c5ccccc5)nc(-c5ccccc5)n4)c3)c2)cc1 ; c1ccc(-c2cc(-c3ccccc3)cc(-c3cnc(-n4c5ccccc5c5cc6c(cc54)sc4ccccc46)c(-c4nc(-c5ccccc5)nc(-c5ccccc5)n4)c3)c2)cc1 ; c1ccc(-c2cc(-c3ccccc3)cc(-c3cnc(-n4c5ccccc5c5ccc6c7ccccc7sc6c54)c(-c4nc(-c5ccccc5)nc(-c5ccccc5)n4)c3)c2)cc1]

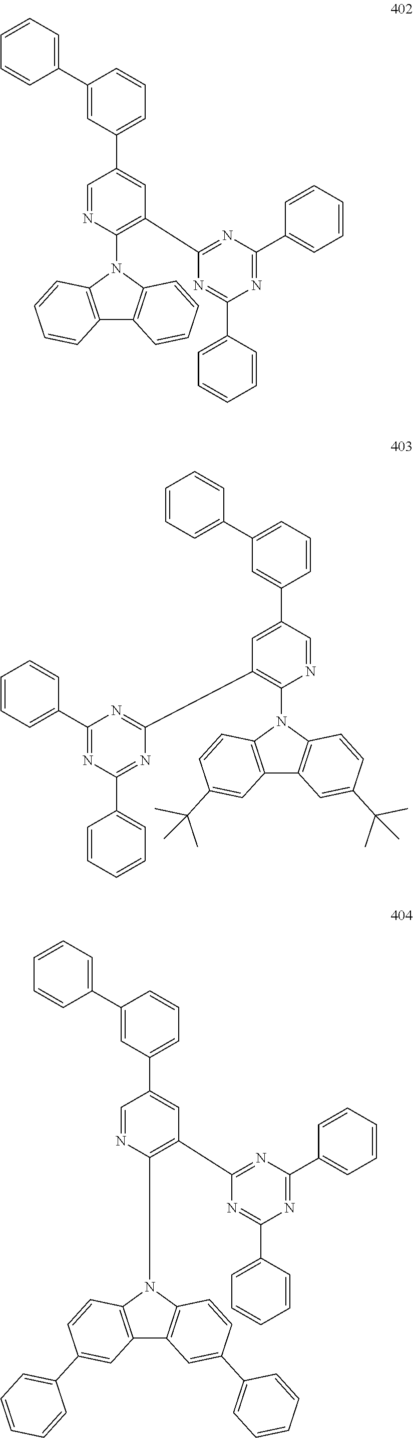 [SMILES: c1ccc(-c2cccc(-c3cnc(-n4c5ccccc5c5ccccc54)c(-c4nc(-c5ccccc5)nc(-c5ccccc5)n4)c3)c2)cc1 ; CC(C)(C)c1ccc2c(c1)c1cc(C(C)(C)C)ccc1n2-c1ncc(-c2cccc(-c3ccccc3)c2)cc1-c1nc(-c2ccccc2)nc(-c2ccccc2)n1 ; c1ccc(-c2cccc(-c3cnc(-n4c5ccc(-c6ccccc6)cc5c5cc(-c6ccccc6)ccc54)c(-c4nc(-c5ccccc5)nc(-c5ccccc5)n4)c3)c2)cc1]

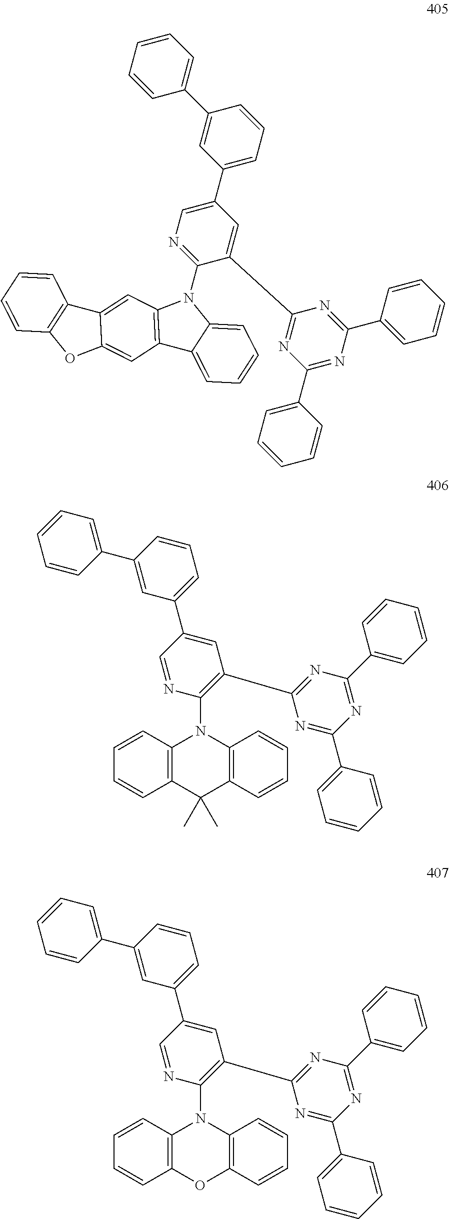 [SMILES: c1ccc(-c2cccc(-c3cnc(-n4c5ccccc5c5cc6oc7ccccc7c6cc54)c(-c4nc(-c5ccccc5)nc(-c5ccccc5)n4)c3)c2)cc1 ; CC1(C)c2ccccc2N(c2ncc(-c3cccc(-c4ccccc4)c3)cc2-c2nc(-c3ccccc3)nc(-c3ccccc3)n2)c2ccccc21 ; c1ccc(-c2cccc(-c3cnc(N4c5ccccc5Oc5ccccc54)c(-c4nc(-c5ccccc5)nc(-c5ccccc5)n4)c3)c2)cc1]

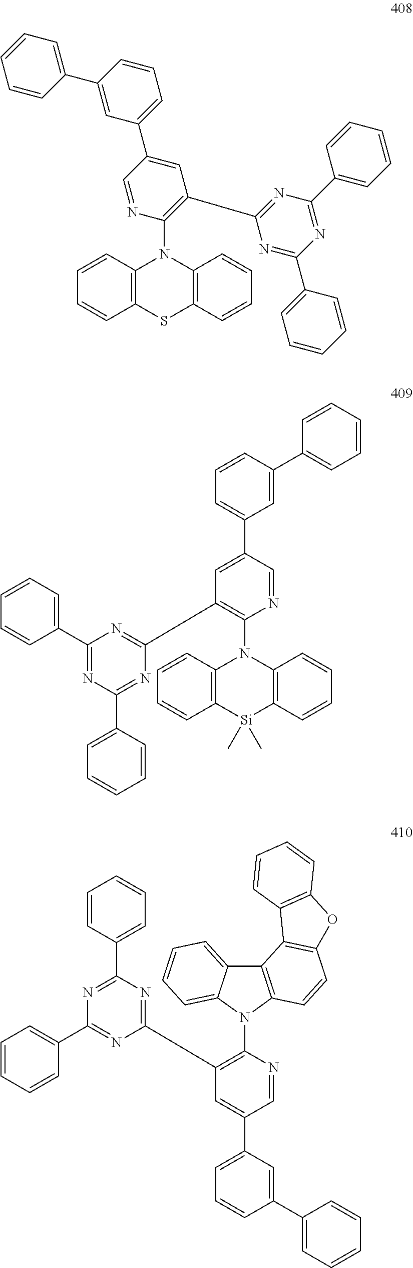 [SMILES: c1ccc(-c2cccc(-c3cnc(N4c5ccccc5Sc5ccccc54)c(-c4nc(-c5ccccc5)nc(-c5ccccc5)n4)c3)c2)cc1 ; C[Si]1(C)c2ccccc2N(c2ncc(-c3cccc(-c4ccccc4)c3)cc2-c2nc(-c3ccccc3)nc(-c3ccccc3)n2)c2ccccc21 ; c1ccc(-c2cccc(-c3cnc(-n4c5ccccc5c5c6c(ccc54)oc4ccccc46)c(-c4nc(-c5ccccc5)nc(-c5ccccc5)n4)c3)c2)cc1]

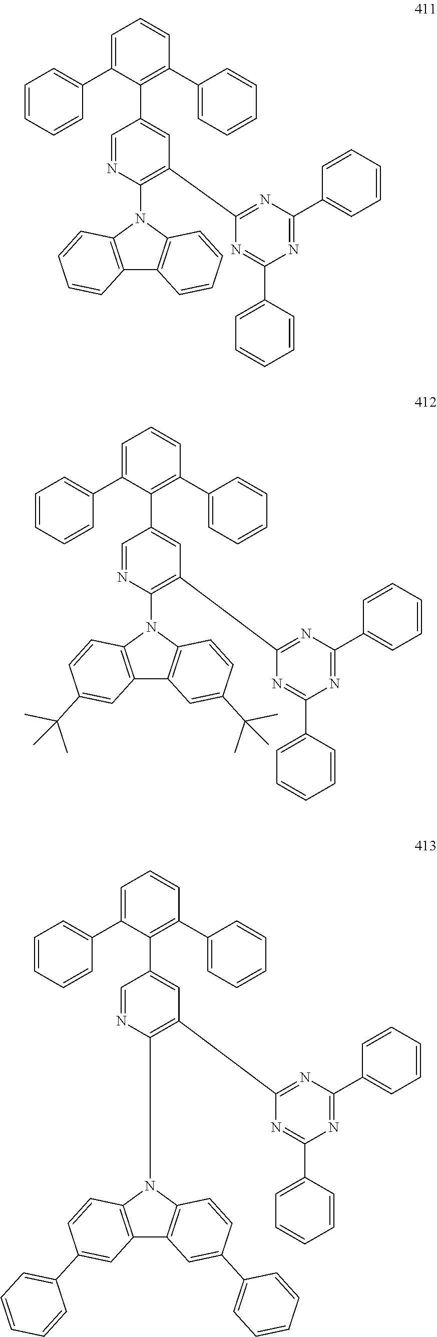 [SMILES: c1ccc(-c2nc(-c3ccccc3)nc(-c3cc(-c4c(-c5ccccc5)cccc4-c4ccccc4)cnc3-n3c4ccccc4c4ccccc43)n2)cc1 ; CC(C)(C)c1ccc2c(c1)c1cc(C(C)(C)C)ccc1n2-c1ncc(-c2c(-c3ccccc3)cccc2-c2ccccc2)cc1-c1nc(-c2ccccc2)nc(-c2ccccc2)n1 ; c1ccc(-c2ccc3c(c2)c2cc(-c4ccccc4)ccc2n3-c2ncc(-c3c(-c4ccccc4)cccc3-c3ccccc3)cc2-c2nc(-c3ccccc3)nc(-c3ccccc3)n2)cc1]

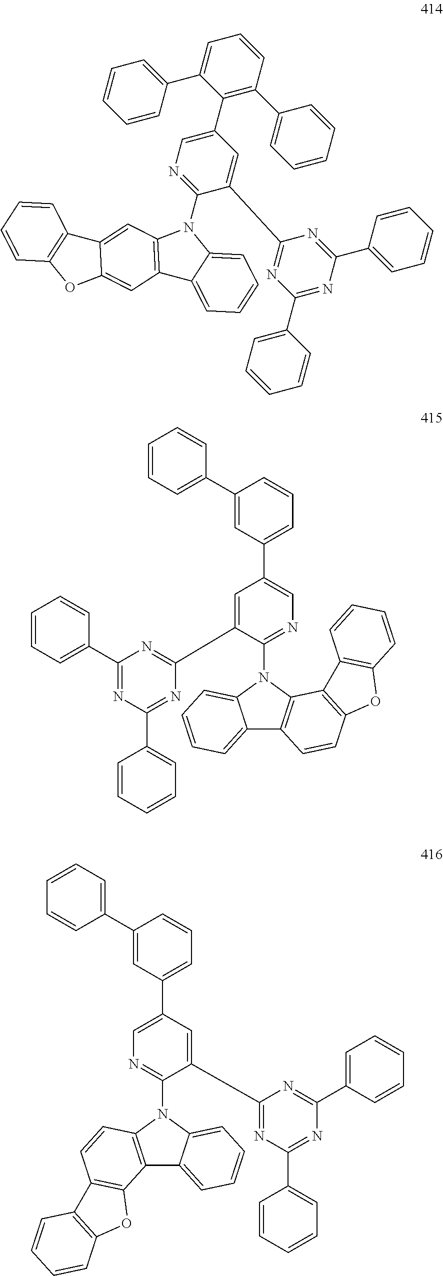 [SMILES: c1ccc(-c2nc(-c3ccccc3)nc(-c3cc(-c4c(-c5ccccc5)cccc4-c4ccccc4)cnc3-n3c4ccccc4c4cc5oc6ccccc6c5cc43)n2)cc1 ; c1ccc(-c2cccc(-c3cnc(-n4c5ccccc5c5ccc6oc7ccccc7c6c54)c(-c4nc(-c5ccccc5)nc(-c5ccccc5)n4)c3)c2)cc1 ; c1ccc(-c2cccc(-c3cnc(-n4c5ccccc5c5c6oc7ccccc7c6ccc54)c(-c4nc(-c5ccccc5)nc(-c5ccccc5)n4)c3)c2)cc1]

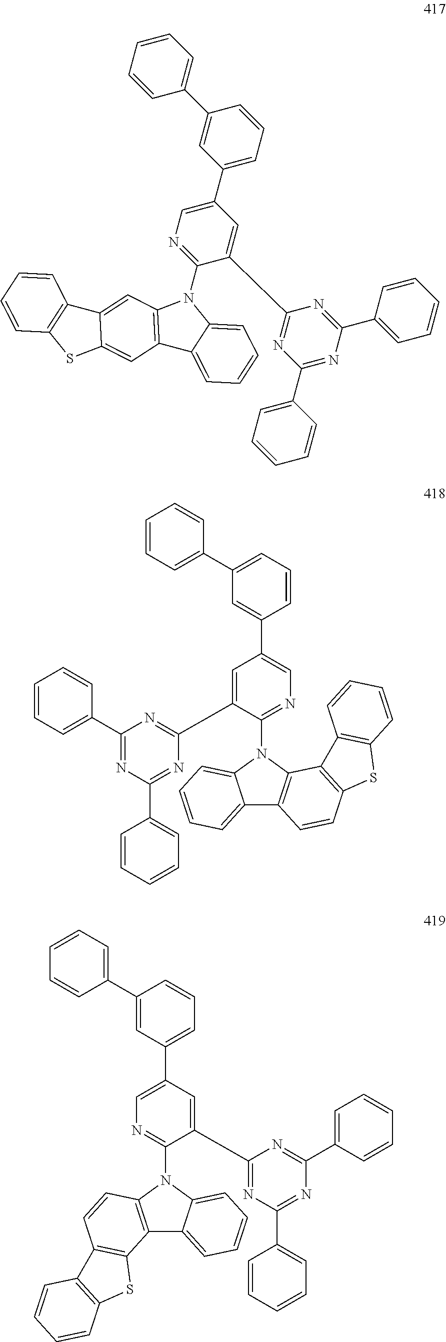 [SMILES: c1ccc(-c2cccc(-c3cnc(-n4c5ccccc5c5cc6sc7ccccc7c6cc54)c(-c4nc(-c5ccccc5)nc(-c5ccccc5)n4)c3)c2)cc1 ; c1ccc(-c2cccc(-c3cnc(-n4c5ccccc5c5ccc6sc7ccccc7c6c54)c(-c4nc(-c5ccccc5)nc(-c5ccccc5)n4)c3)c2)cc1 ; c1ccc(-c2cccc(-c3cnc(-n4c5ccccc5c5c6sc7ccccc7c6ccc54)c(-c4nc(-c5ccccc5)nc(-c5ccccc5)n4)c3)c2)cc1]

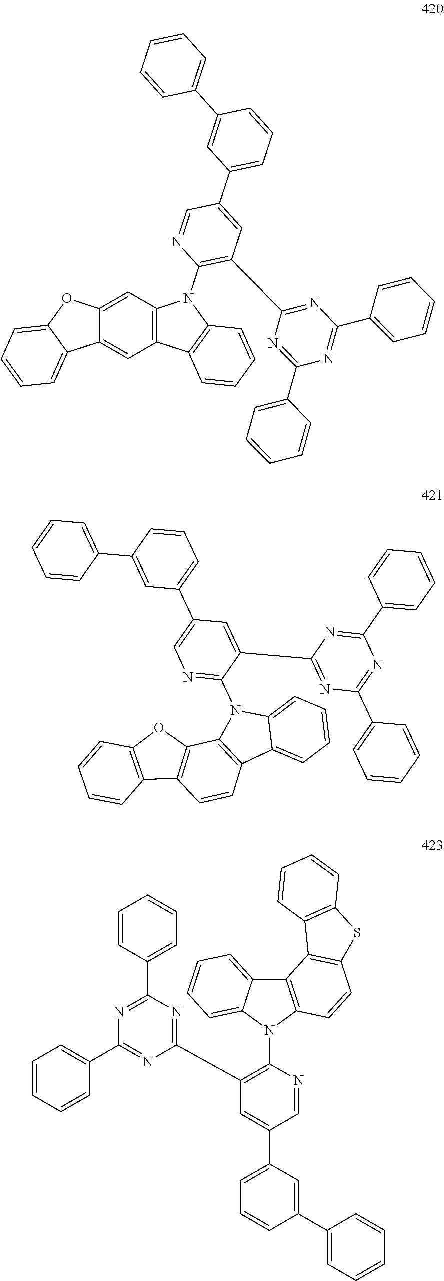 [SMILES: c1ccc(-c2cccc(-c3cnc(-n4c5ccccc5c5cc6c(cc54)oc4ccccc46)c(-c4nc(-c5ccccc5)nc(-c5ccccc5)n4)c3)c2)cc1 ; c1ccc(-c2cccc(-c3cnc(-n4c5ccccc5c5ccc6c7ccccc7oc6c54)c(-c4nc(-c5ccccc5)nc(-c5ccccc5)n4)c3)c2)cc1 ; c1ccc(-c2cccc(-c3cnc(-n4c5ccccc5c5c6c(ccc54)sc4ccccc46)c(-c4nc(-c5ccccc5)nc(-c5ccccc5)n4)c3)c2)cc1]

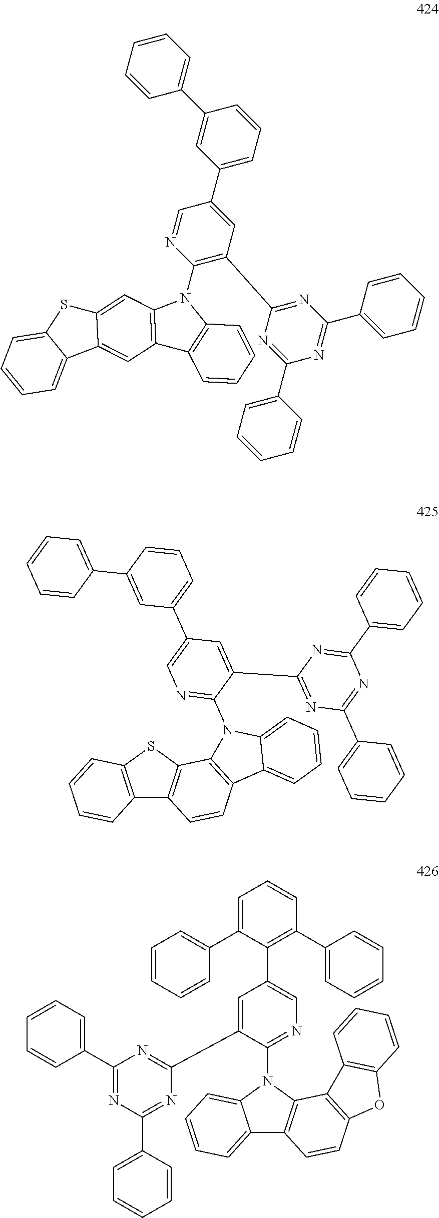 [SMILES: c1ccc(-c2cccc(-c3cnc(-n4c5ccccc5c5cc6c(cc54)sc4ccccc46)c(-c4nc(-c5ccccc5)nc(-c5ccccc5)n4)c3)c2)cc1 ; c1ccc(-c2cccc(-c3cnc(-n4c5ccccc5c5ccc6c7ccccc7sc6c54)c(-c4nc(-c5ccccc5)nc(-c5ccccc5)n4)c3)c2)cc1 ; c1ccc(-c2nc(-c3ccccc3)nc(-c3cc(-c4c(-c5ccccc5)cccc4-c4ccccc4)cnc3-n3c4ccccc4c4ccc5oc6ccccc6c5c43)n2)cc1]

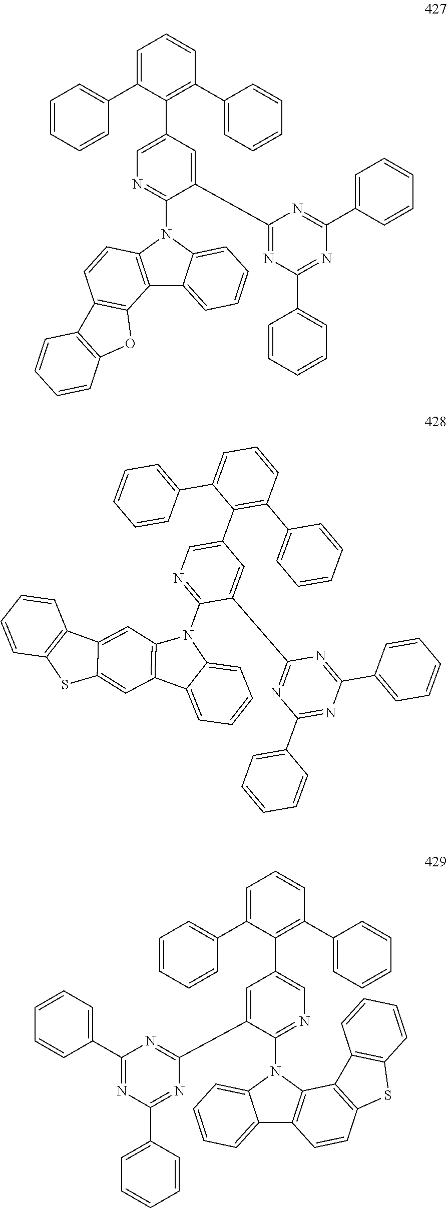 [SMILES: c1ccc(-c2nc(-c3ccccc3)nc(-c3cc(-c4c(-c5ccccc5)cccc4-c4ccccc4)cnc3-n3c4ccccc4c4c5oc6ccccc6c5ccc43)n2)cc1 ; c1ccc(-c2nc(-c3ccccc3)nc(-c3cc(-c4c(-c5ccccc5)cccc4-c4ccccc4)cnc3-n3c4ccccc4c4cc5sc6ccccc6c5cc43)n2)cc1 ; c1ccc(-c2nc(-c3ccccc3)nc(-c3cc(-c4c(-c5ccccc5)cccc4-c4ccccc4)cnc3-n3c4ccccc4c4ccc5sc6ccccc6c5c43)n2)cc1]

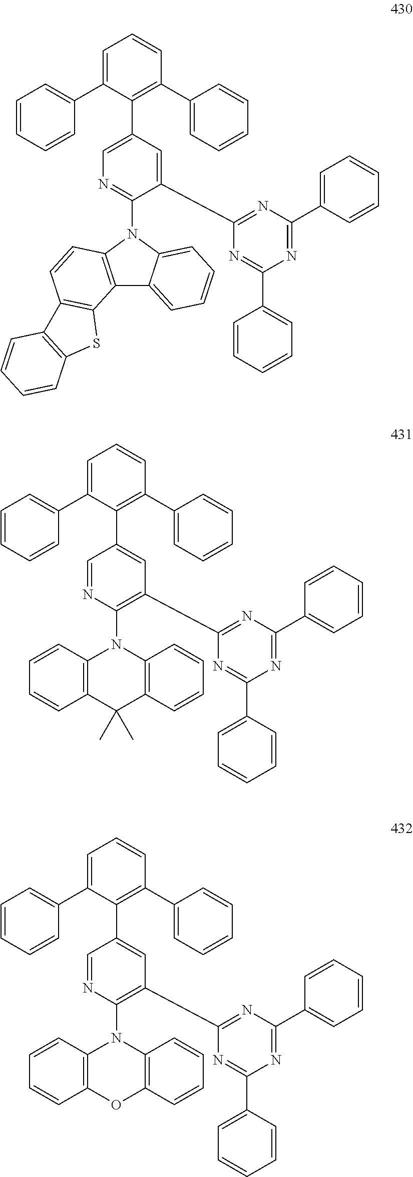 [SMILES: c1ccc(-c2nc(-c3ccccc3)nc(-c3cc(-c4c(-c5ccccc5)cccc4-c4ccccc4)cnc3-n3c4ccccc4c4c5sc6ccccc6c5ccc43)n2)cc1 ; CC1(C)c2ccccc2N(c2ncc(-c3c(-c4ccccc4)cccc3-c3ccccc3)cc2-c2nc(-c3ccccc3)nc(-c3ccccc3)n2)c2ccccc21 ; c1ccc(-c2nc(-c3ccccc3)nc(-c3cc(-c4c(-c5ccccc5)cccc4-c4ccccc4)cnc3N3c4ccccc4Oc4ccccc43)n2)cc1]

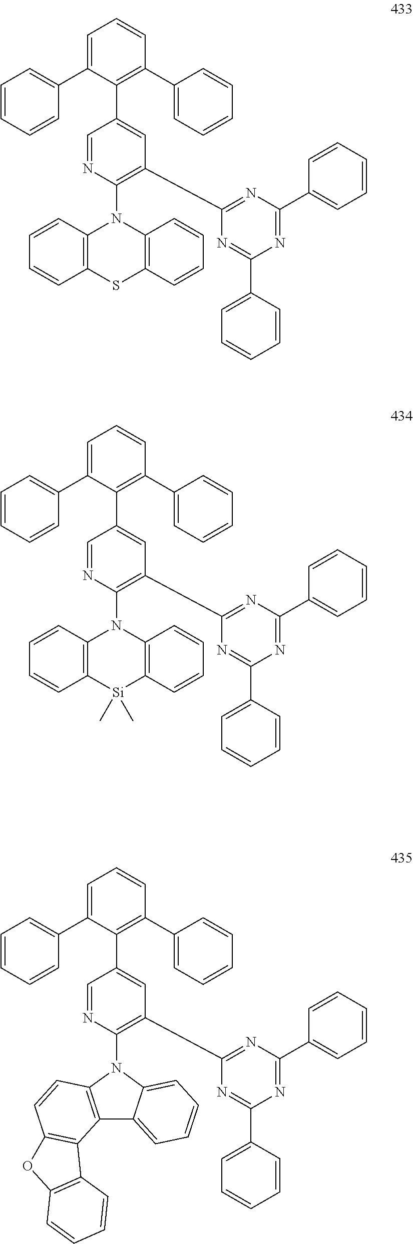 [SMILES: c1ccc(-c2nc(-c3ccccc3)nc(-c3cc(-c4c(-c5ccccc5)cccc4-c4ccccc4)cnc3N3c4ccccc4Sc4ccccc43)n2)cc1 ; C[Si]1(C)c2ccccc2N(c2ncc(-c3c(-c4ccccc4)cccc3-c3ccccc3)cc2-c2nc(-c3ccccc3)nc(-c3ccccc3)n2)c2ccccc21 ; c1ccc(-c2nc(-c3ccccc3)nc(-c3cc(-c4c(-c5ccccc5)cccc4-c4ccccc4)cnc3-n3c4ccccc4c4c5c(ccc43)oc3ccccc35)n2)cc1]

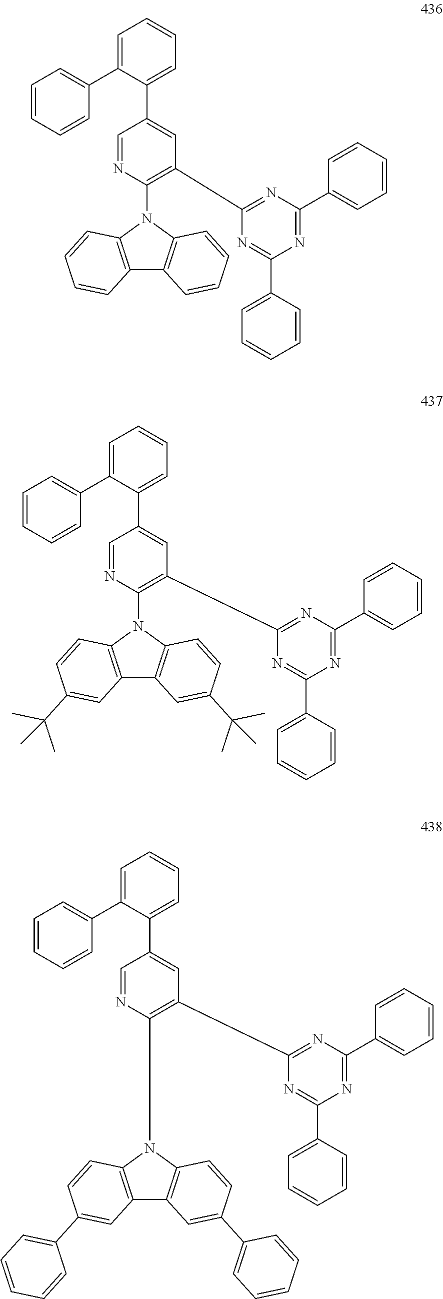 [SMILES: c1ccc(-c2nc(-c3ccccc3)nc(-c3cc(-c4ccccc4-c4ccccc4)cnc3-n3c4ccccc4c4ccccc43)n2)cc1 ; CC(C)(C)c1ccc2c(c1)c1cc(C(C)(C)C)ccc1n2-c1ncc(-c2ccccc2-c2ccccc2)cc1-c1nc(-c2ccccc2)nc(-c2ccccc2)n1 ; c1ccc(-c2ccc3c(c2)c2cc(-c4ccccc4)ccc2n3-c2ncc(-c3ccccc3-c3ccccc3)cc2-c2nc(-c3ccccc3)nc(-c3ccccc3)n2)cc1]

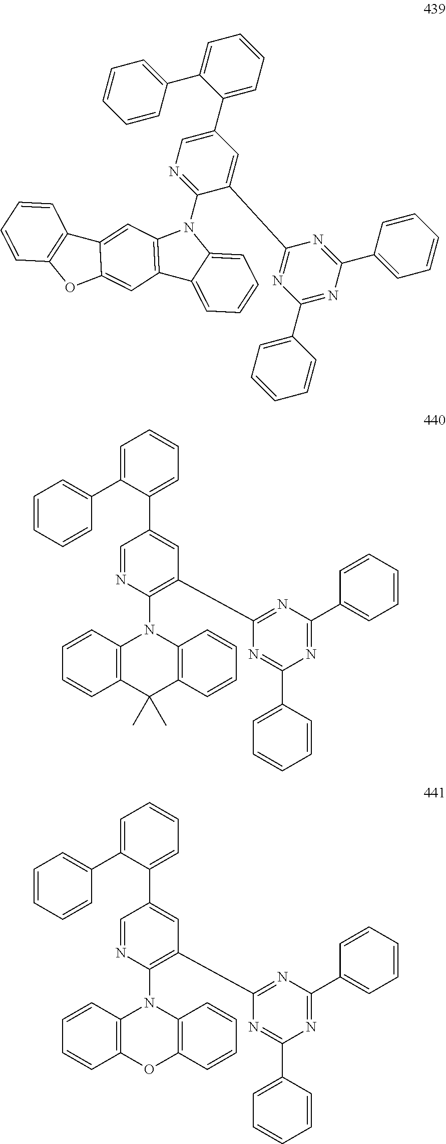 [SMILES: c1ccc(-c2nc(-c3ccccc3)nc(-c3cc(-c4ccccc4-c4ccccc4)cnc3-n3c4ccccc4c4cc5oc6ccccc6c5cc43)n2)cc1 ; CC1(C)c2ccccc2N(c2ncc(-c3ccccc3-c3ccccc3)cc2-c2nc(-c3ccccc3)nc(-c3ccccc3)n2)c2ccccc21 ; c1ccc(-c2nc(-c3ccccc3)nc(-c3cc(-c4ccccc4-c4ccccc4)cnc3N3c4ccccc4Oc4ccccc43)n2)cc1]

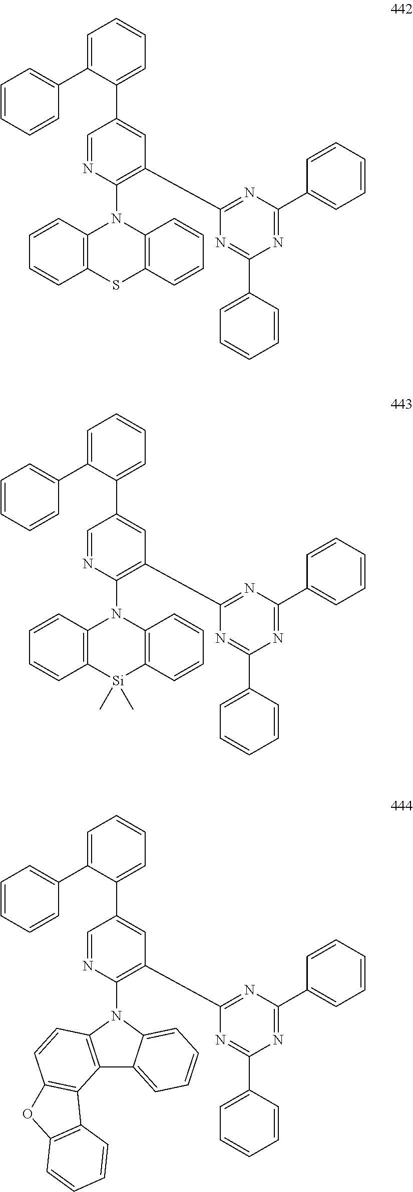 [SMILES: c1ccc(-c2nc(-c3ccccc3)nc(-c3cc(-c4ccccc4-c4ccccc4)cnc3N3c4ccccc4Sc4ccccc43)n2)cc1 ; C[Si]1(C)c2ccccc2N(c2ncc(-c3ccccc3-c3ccccc3)cc2-c2nc(-c3ccccc3)nc(-c3ccccc3)n2)c2ccccc21 ; c1ccc(-c2nc(-c3ccccc3)nc(-c3cc(-c4ccccc4-c4ccccc4)cnc3-n3c4ccccc4c4c5c(ccc43)oc3ccccc35)n2)cc1]

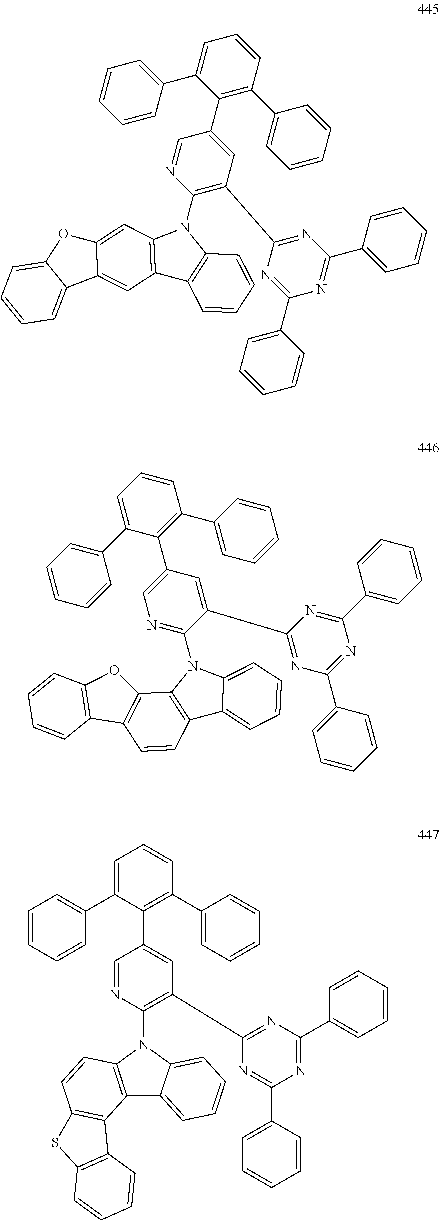 [SMILES: c1ccc(-c2nc(-c3ccccc3)nc(-c3cc(-c4c(-c5ccccc5)cccc4-c4ccccc4)cnc3-n3c4ccccc4c4cc5c(cc43)oc3ccccc35)n2)cc1 ; c1ccc(-c2nc(-c3ccccc3)nc(-c3cc(-c4c(-c5ccccc5)cccc4-c4ccccc4)cnc3-n3c4ccccc4c4ccc5c6ccccc6oc5c43)n2)cc1 ; c1ccc(-c2nc(-c3ccccc3)nc(-c3cc(-c4c(-c5ccccc5)cccc4-c4ccccc4)cnc3-n3c4ccccc4c4c5c(ccc43)sc3ccccc35)n2)cc1]

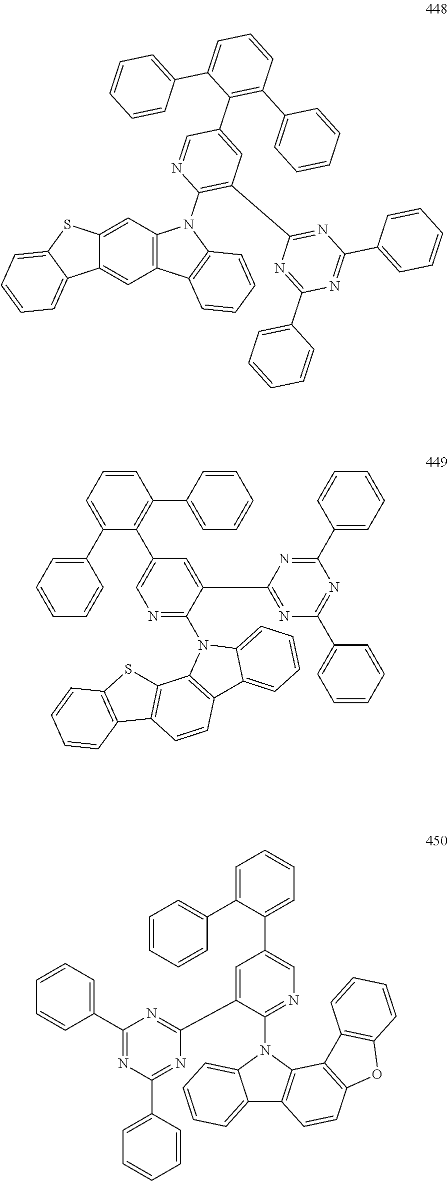 [SMILES: c1ccc(-c2nc(-c3ccccc3)nc(-c3cc(-c4c(-c5ccccc5)cccc4-c4ccccc4)cnc3-n3c4ccccc4c4cc5c(cc43)sc3ccccc35)n2)cc1 ; c1ccc(-c2nc(-c3ccccc3)nc(-c3cc(-c4c(-c5ccccc5)cccc4-c4ccccc4)cnc3-n3c4ccccc4c4ccc5c6ccccc6sc5c43)n2)cc1 ; c1ccc(-c2nc(-c3ccccc3)nc(-c3cc(-c4ccccc4-c4ccccc4)cnc3-n3c4ccccc4c4ccc5oc6ccccc6c5c43)n2)cc1]

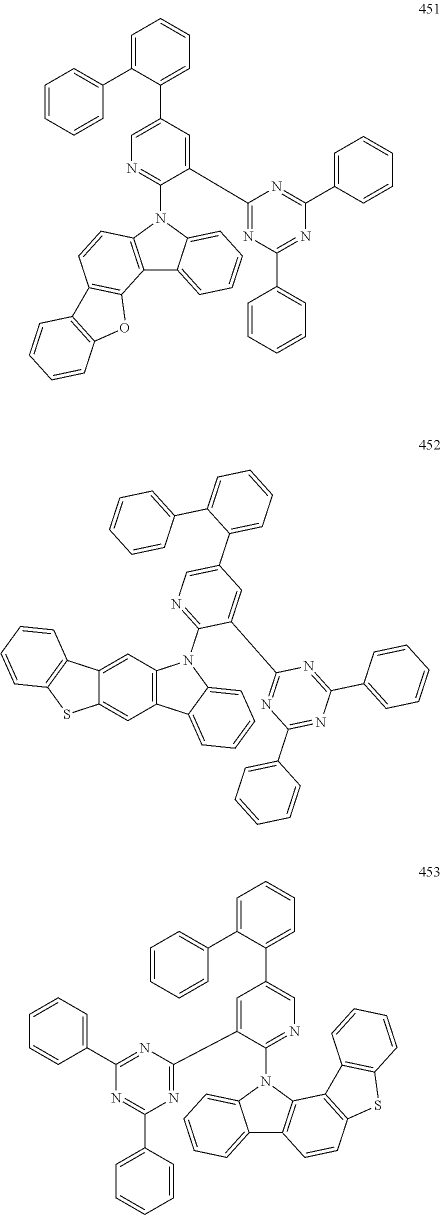 [SMILES: c1ccc(-c2nc(-c3ccccc3)nc(-c3cc(-c4ccccc4-c4ccccc4)cnc3-n3c4ccccc4c4c5oc6ccccc6c5ccc43)n2)cc1 ; c1ccc(-c2nc(-c3ccccc3)nc(-c3cc(-c4ccccc4-c4ccccc4)cnc3-n3c4ccccc4c4cc5sc6ccccc6c5cc43)n2)cc1 ; c1ccc(-c2nc(-c3ccccc3)nc(-c3cc(-c4ccccc4-c4ccccc4)cnc3-n3c4ccccc4c4ccc5sc6ccccc6c5c43)n2)cc1]

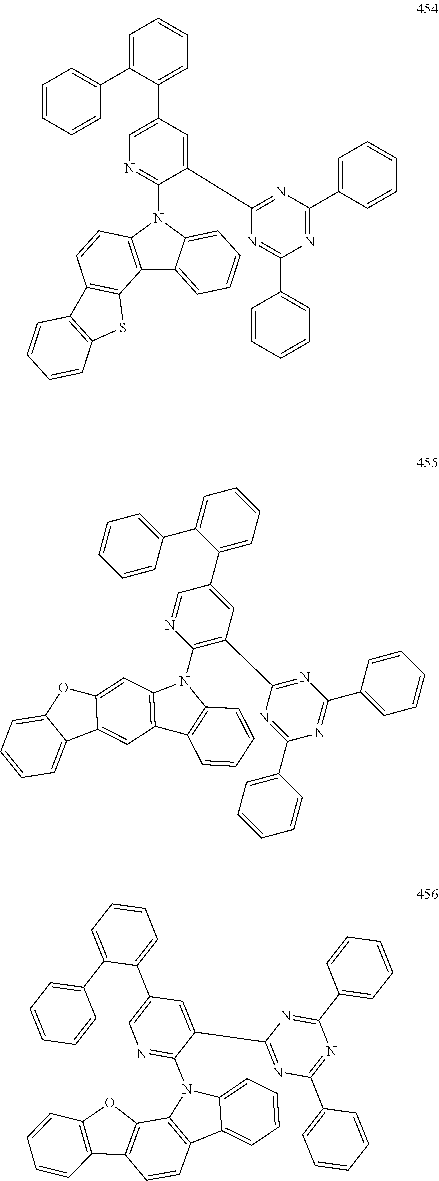 [SMILES: c1ccc(-c2nc(-c3ccccc3)nc(-c3cc(-c4ccccc4-c4ccccc4)cnc3-n3c4ccccc4c4c5sc6ccccc6c5ccc43)n2)cc1 ; c1ccc(-c2nc(-c3ccccc3)nc(-c3cc(-c4ccccc4-c4ccccc4)cnc3-n3c4ccccc4c4cc5c(cc43)oc3ccccc35)n2)cc1 ; c1ccc(-c2nc(-c3ccccc3)nc(-c3cc(-c4ccccc4-c4ccccc4)cnc3-n3c4ccccc4c4ccc5c6ccccc6oc5c43)n2)cc1]

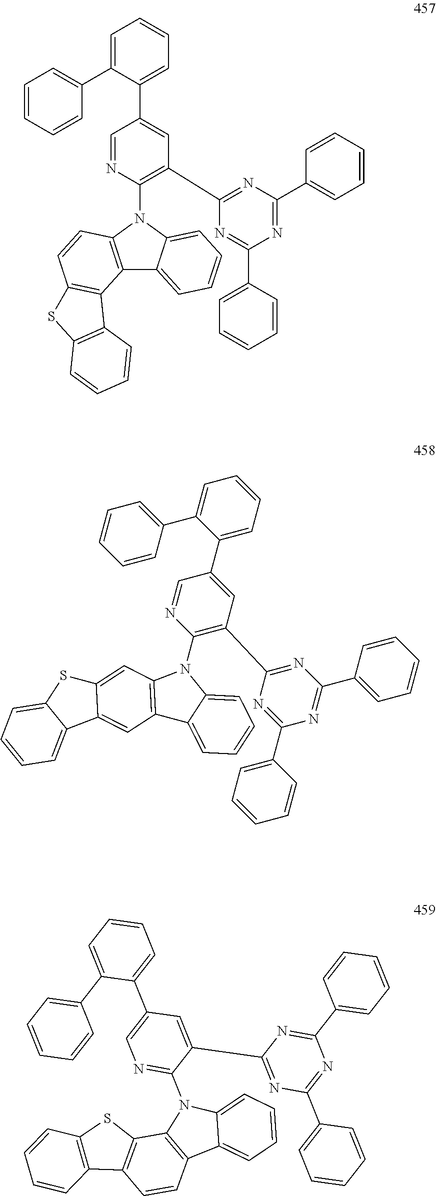 [SMILES: c1ccc(-c2nc(-c3ccccc3)nc(-c3cc(-c4ccccc4-c4ccccc4)cnc3-n3c4ccccc4c4c5c(ccc43)sc3ccccc35)n2)cc1 ; c1ccc(-c2nc(-c3ccccc3)nc(-c3cc(-c4ccccc4-c4ccccc4)cnc3-n3c4ccccc4c4cc5c(cc43)sc3ccccc35)n2)cc1 ; c1ccc(-c2nc(-c3ccccc3)nc(-c3cc(-c4ccccc4-c4ccccc4)cnc3-n3c4ccccc4c4ccc5c6ccccc6sc5c43)n2)cc1]

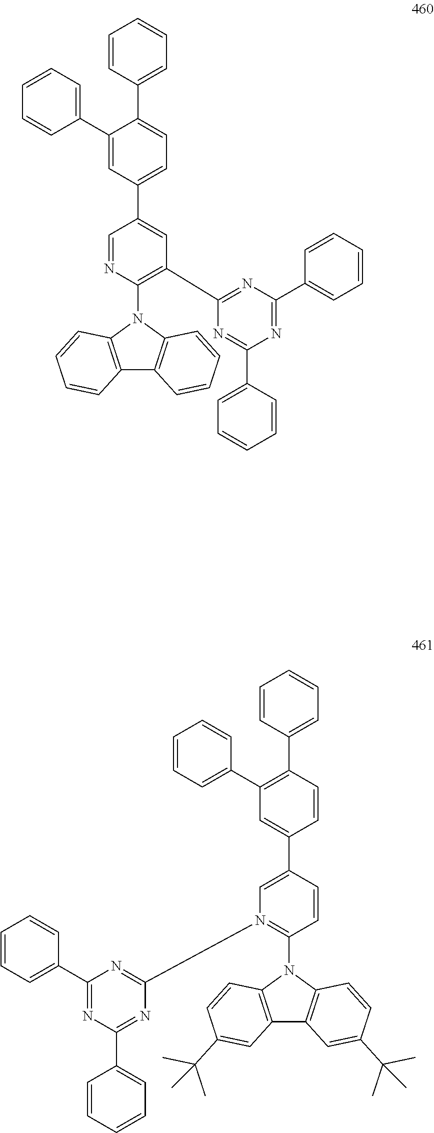

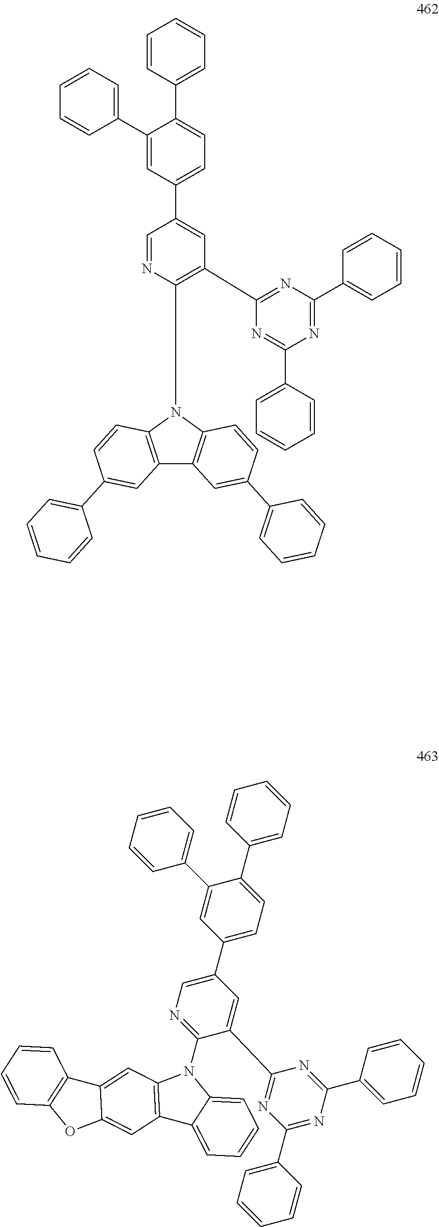 [SMILES: c1ccc(-c2ccc3c(c2)c2cc(-c4ccccc4)ccc2n3-c2ncc(-c3ccc(-c4ccccc4)c(-c4ccccc4)c3)cc2-c2nc(-c3ccccc3)nc(-c3ccccc3)n2)cc1 ; c1ccc(-c2nc(-c3ccccc3)nc(-c3cc(-c4ccc(-c5ccccc5)c(-c5ccccc5)c4)cnc3-n3c4ccccc4c4cc5oc6ccccc6c5cc43)n2)cc1]

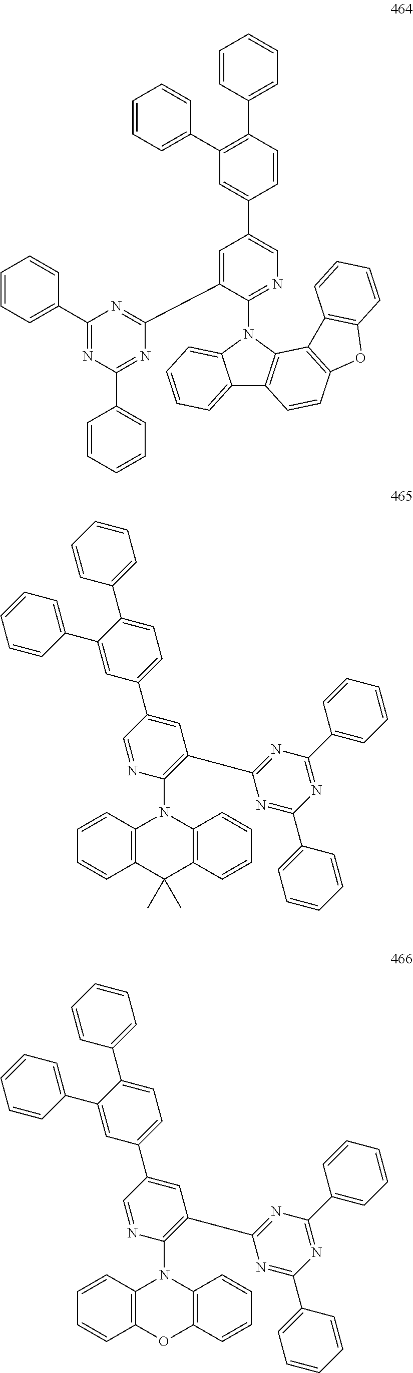 [SMILES: c1ccc(-c2nc(-c3ccccc3)nc(-c3cc(-c4ccc(-c5ccccc5)c(-c5ccccc5)c4)cnc3-n3c4ccccc4c4ccc5oc6ccccc6c5c43)n2)cc1 ; CC1(C)c2ccccc2N(c2ncc(-c3ccc(-c4ccccc4)c(-c4ccccc4)c3)cc2-c2nc(-c3ccccc3)nc(-c3ccccc3)n2)c2ccccc21 ; c1ccc(-c2nc(-c3ccccc3)nc(-c3cc(-c4ccc(-c5ccccc5)c(-c5ccccc5)c4)cnc3N3c4ccccc4Oc4ccccc43)n2)cc1]

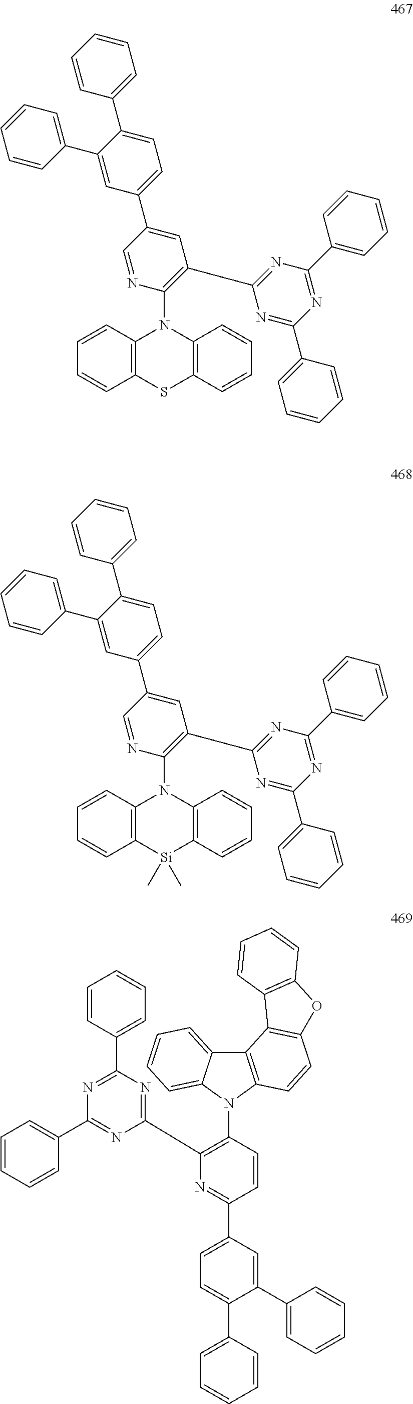 [SMILES: c1ccc(-c2nc(-c3ccccc3)nc(-c3cc(-c4ccc(-c5ccccc5)c(-c5ccccc5)c4)cnc3N3c4ccccc4Sc4ccccc43)n2)cc1 ; C[Si]1(C)c2ccccc2N(c2ncc(-c3ccc(-c4ccccc4)c(-c4ccccc4)c3)cc2-c2nc(-c3ccccc3)nc(-c3ccccc3)n2)c2ccccc21 ; c1ccc(-c2nc(-c3ccccc3)nc(-c3nc(-c4ccc(-c5ccccc5)c(-c5ccccc5)c4)ccc3-n3c4ccccc4c4c5c(ccc43)oc3ccccc35)n2)cc1]

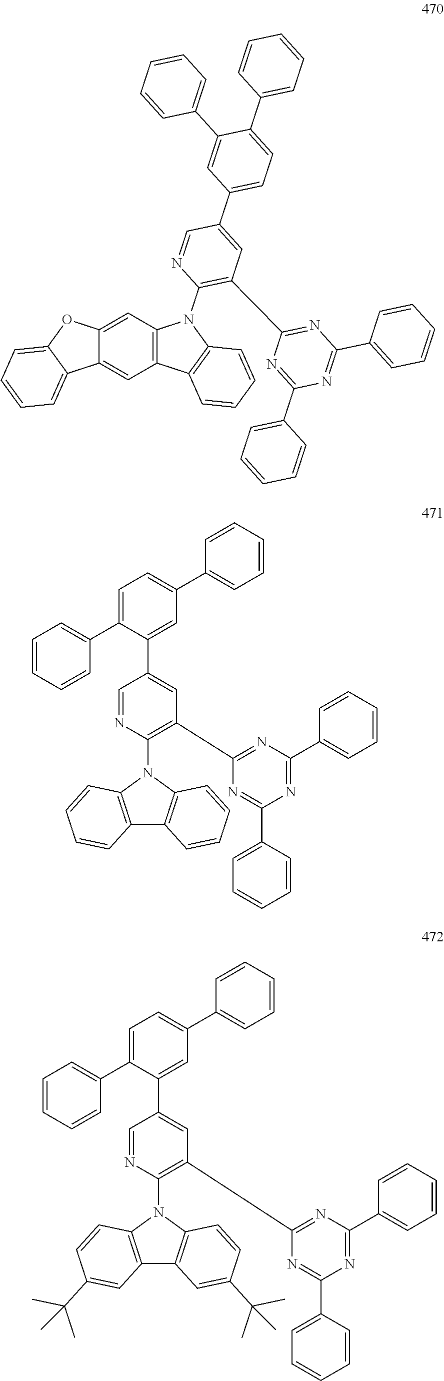 [SMILES: c1ccc(-c2nc(-c3ccccc3)nc(-c3cc(-c4ccc(-c5ccccc5)c(-c5ccccc5)c4)cnc3-n3c4ccccc4c4cc5c(cc43)oc3ccccc35)n2)cc1 ; c1ccc(-c2ccc(-c3ccccc3)c(-c3cnc(-n4c5ccccc5c5ccccc54)c(-c4nc(-c5ccccc5)nc(-c5ccccc5)n4)c3)c2)cc1 ; CC(C)(C)c1ccc2c(c1)c1cc(C(C)(C)C)ccc1n2-c1ncc(-c2cc(-c3ccccc3)ccc2-c2ccccc2)cc1-c1nc(-c2ccccc2)nc(-c2ccccc2)n1]

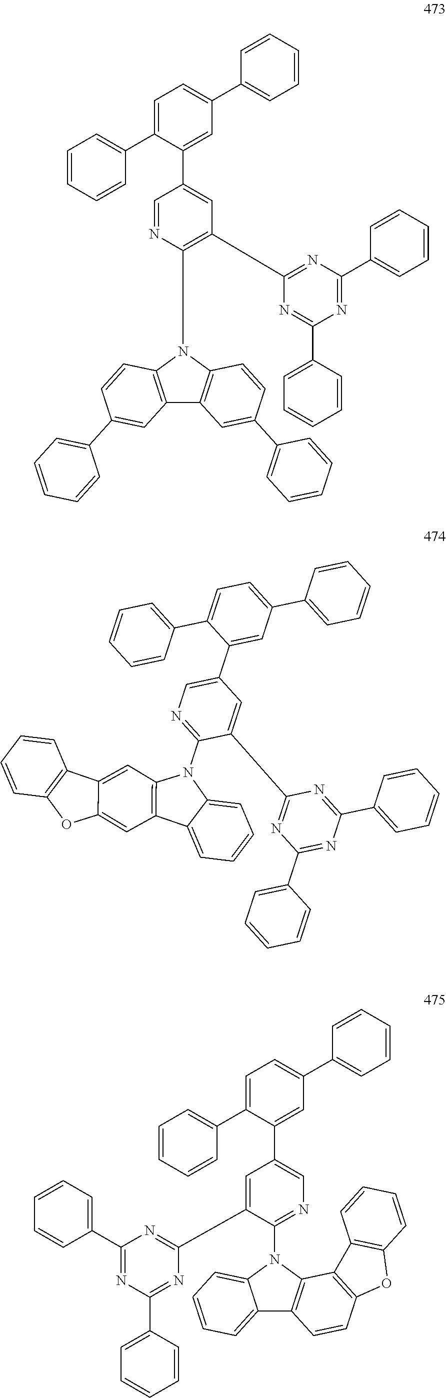 [SMILES: c1ccc(-c2ccc(-c3ccccc3)c(-c3cnc(-n4c5ccc(-c6ccccc6)cc5c5cc(-c6ccccc6)ccc54)c(-c4nc(-c5ccccc5)nc(-c5ccccc5)n4)c3)c2)cc1 ; c1ccc(-c2ccc(-c3ccccc3)c(-c3cnc(-n4c5ccccc5c5cc6oc7ccccc7c6cc54)c(-c4nc(-c5ccccc5)nc(-c5ccccc5)n4)c3)c2)cc1 ; c1ccc(-c2ccc(-c3ccccc3)c(-c3cnc(-n4c5ccccc5c5ccc6oc7ccccc7c6c54)c(-c4nc(-c5ccccc5)nc(-c5ccccc5)n4)c3)c2)cc1]

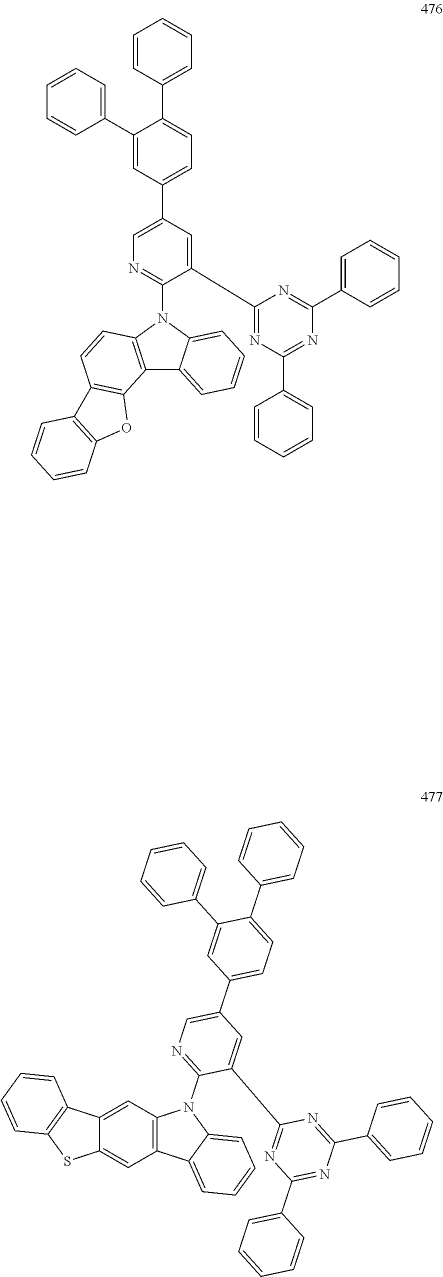 [SMILES: c1ccc(-c2nc(-c3ccccc3)nc(-c3cc(-c4ccc(-c5ccccc5)c(-c5ccccc5)c4)cnc3-n3c4ccccc4c4c5oc6ccccc6c5ccc43)n2)cc1 ; c1ccc(-c2nc(-c3ccccc3)nc(-c3cc(-c4ccc(-c5ccccc5)c(-c5ccccc5)c4)cnc3-n3c4ccccc4c4cc5sc6ccccc6c5cc43)n2)cc1]

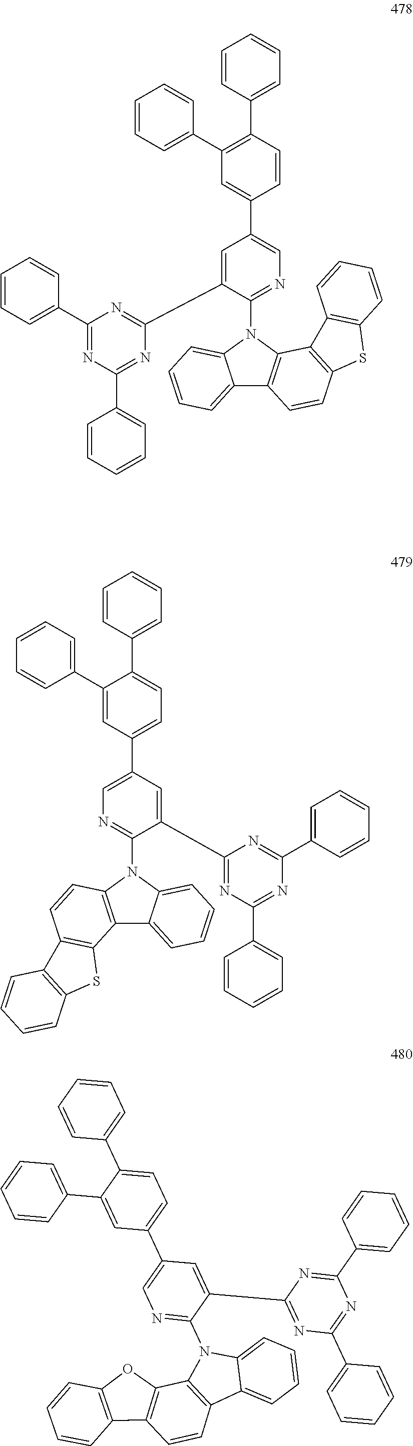 [SMILES: c1ccc(-c2nc(-c3ccccc3)nc(-c3cc(-c4ccc(-c5ccccc5)c(-c5ccccc5)c4)cnc3-n3c4ccccc4c4ccc5sc6ccccc6c5c43)n2)cc1 ; c1ccc(-c2nc(-c3ccccc3)nc(-c3cc(-c4ccc(-c5ccccc5)c(-c5ccccc5)c4)cnc3-n3c4ccccc4c4c5sc6ccccc6c5ccc43)n2)cc1 ; c1ccc(-c2nc(-c3ccccc3)nc(-c3cc(-c4ccc(-c5ccccc5)c(-c5ccccc5)c4)cnc3-n3c4ccccc4c4ccc5c6ccccc6oc5c43)n2)cc1]

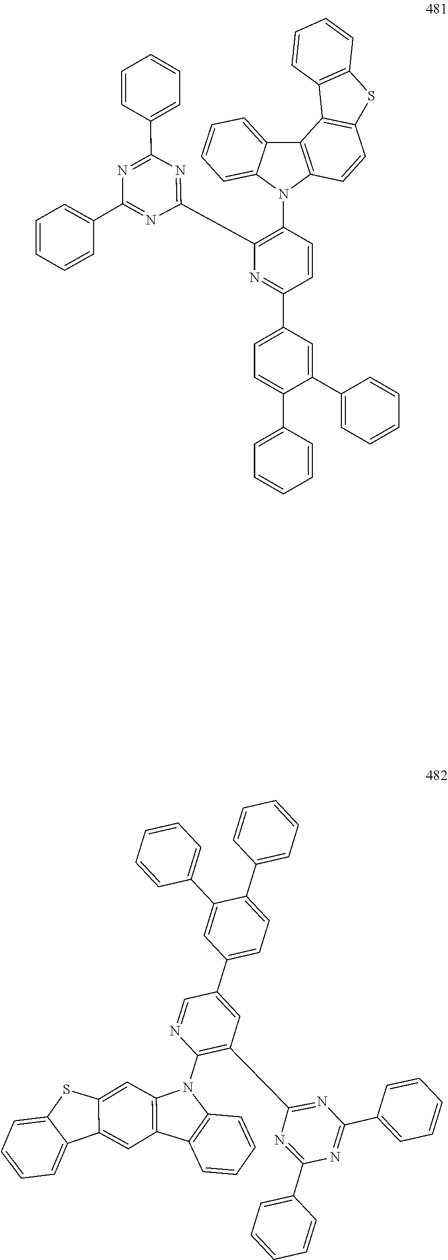 [SMILES: c1ccc(-c2nc(-c3ccccc3)nc(-c3nc(-c4ccc(-c5ccccc5)c(-c5ccccc5)c4)ccc3-n3c4ccccc4c4c5c(ccc43)sc3ccccc35)n2)cc1 ; c1ccc(-c2nc(-c3ccccc3)nc(-c3cc(-c4ccc(-c5ccccc5)c(-c5ccccc5)c4)cnc3-n3c4ccccc4c4cc5c(cc43)sc3ccccc35)n2)cc1]

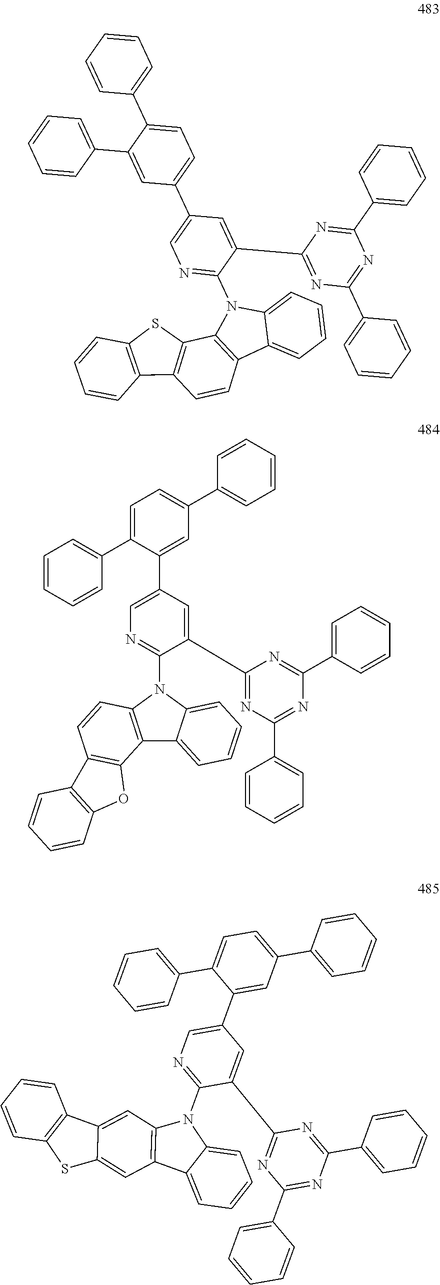 [SMILES: c1ccc(-c2nc(-c3ccccc3)nc(-c3cc(-c4ccc(-c5ccccc5)c(-c5ccccc5)c4)cnc3-n3c4ccccc4c4ccc5c6ccccc6sc5c43)n2)cc1 ; c1ccc(-c2ccc(-c3ccccc3)c(-c3cnc(-n4c5ccccc5c5c6oc7ccccc7c6ccc54)c(-c4nc(-c5ccccc5)nc(-c5ccccc5)n4)c3)c2)cc1 ; c1ccc(-c2ccc(-c3ccccc3)c(-c3cnc(-n4c5ccccc5c5cc6sc7ccccc7c6cc54)c(-c4nc(-c5ccccc5)nc(-c5ccccc5)n4)c3)c2)cc1]

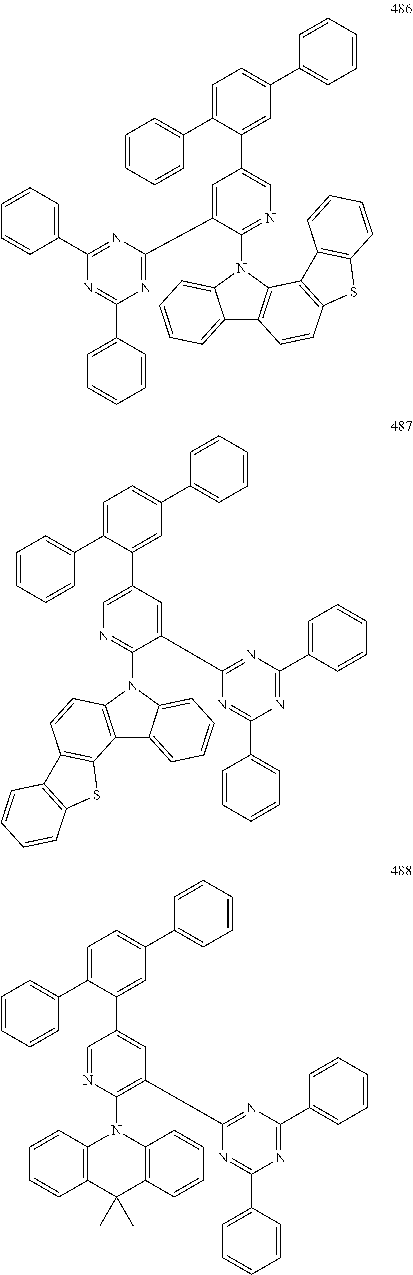 [SMILES: c1ccc(-c2ccc(-c3ccccc3)c(-c3cnc(-n4c5ccccc5c5ccc6sc7ccccc7c6c54)c(-c4nc(-c5ccccc5)nc(-c5ccccc5)n4)c3)c2)cc1 ; c1ccc(-c2ccc(-c3ccccc3)c(-c3cnc(-n4c5ccccc5c5c6sc7ccccc7c6ccc54)c(-c4nc(-c5ccccc5)nc(-c5ccccc5)n4)c3)c2)cc1 ; CC1(C)c2ccccc2N(c2ncc(-c3cc(-c4ccccc4)ccc3-c3ccccc3)cc2-c2nc(-c3ccccc3)nc(-c3ccccc3)n2)c2ccccc21]

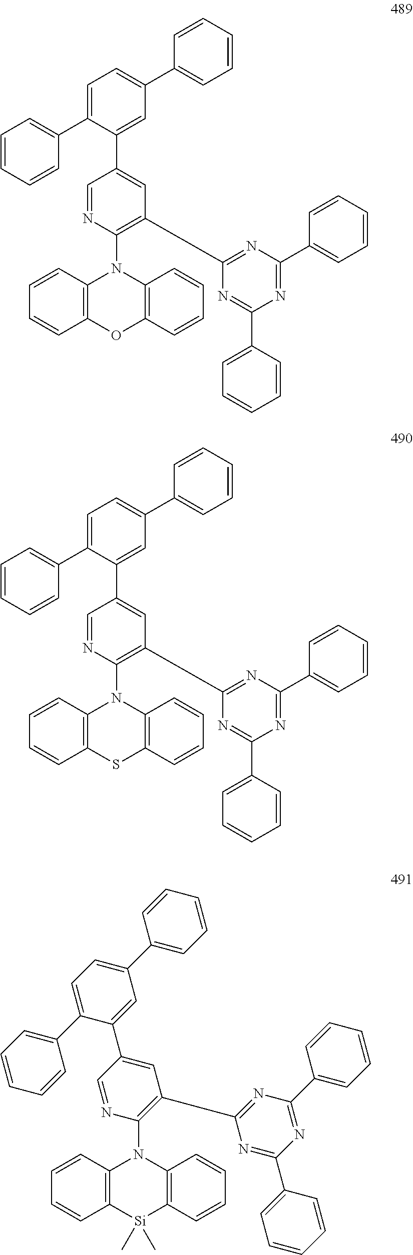 [SMILES: c1ccc(-c2ccc(-c3ccccc3)c(-c3cnc(N4c5ccccc5Oc5ccccc54)c(-c4nc(-c5ccccc5)nc(-c5ccccc5)n4)c3)c2)cc1 ; c1ccc(-c2ccc(-c3ccccc3)c(-c3cnc(N4c5ccccc5Sc5ccccc54)c(-c4nc(-c5ccccc5)nc(-c5ccccc5)n4)c3)c2)cc1 ; C[Si]1(C)c2ccccc2N(c2ncc(-c3cc(-c4ccccc4)ccc3-c3ccccc3)cc2-c2nc(-c3ccccc3)nc(-c3ccccc3)n2)c2ccccc21]

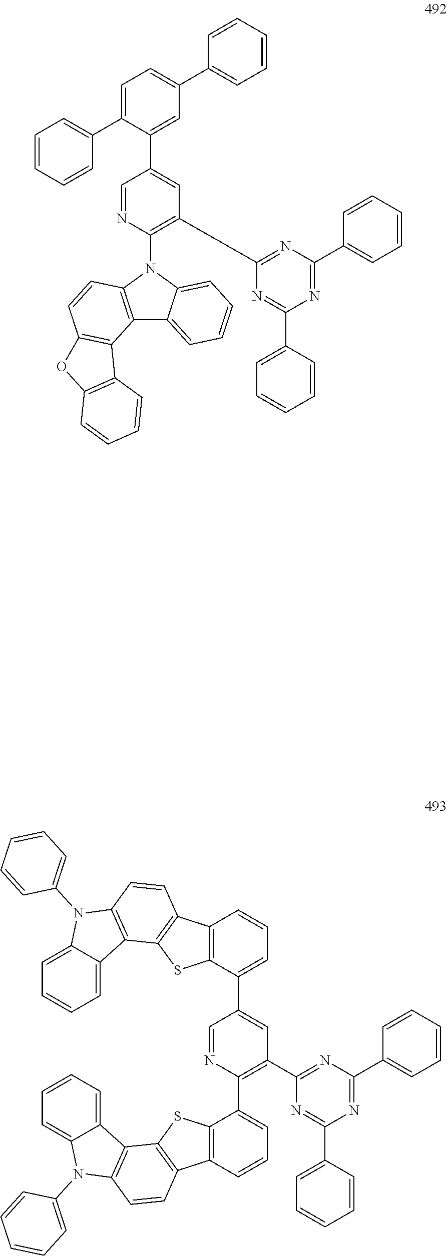 [SMILES: c1ccc(-c2ccc(-c3ccccc3)c(-c3cnc(-n4c5ccccc5c5c6c(ccc54)oc4ccccc46)c(-c4nc(-c5ccccc5)nc(-c5ccccc5)n4)c3)c2)cc1 ; c1ccc(-c2nc(-c3ccccc3)nc(-c3cc(-c4cccc5c4sc4c5ccc5c4c4ccccc4n5-c4ccccc4)cnc3-c3cccc4c3sc3c4ccc4c3c3ccccc3n4-c3ccccc3)n2)cc1]

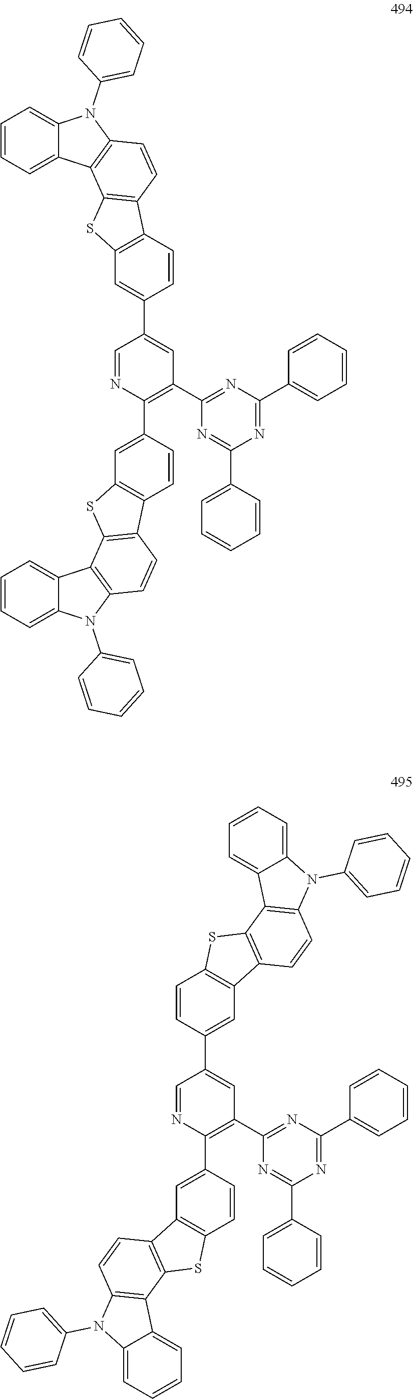 [SMILES: c1ccc(-c2nc(-c3ccccc3)nc(-c3cc(-c4ccc5c(c4)sc4c5ccc5c4c4ccccc4n5-c4ccccc4)cnc3-c3ccc4c(c3)sc3c4ccc4c3c3ccccc3n4-c3ccccc3)n2)cc1 ; c1ccc(-c2nc(-c3ccccc3)nc(-c3cc(-c4ccc5sc6c(ccc7c6c6ccccc6n7-c6ccccc6)c5c4)cnc3-c3ccc4sc5c(ccc6c5c5ccccc5n6-c5ccccc5)c4c3)n2)cc1]

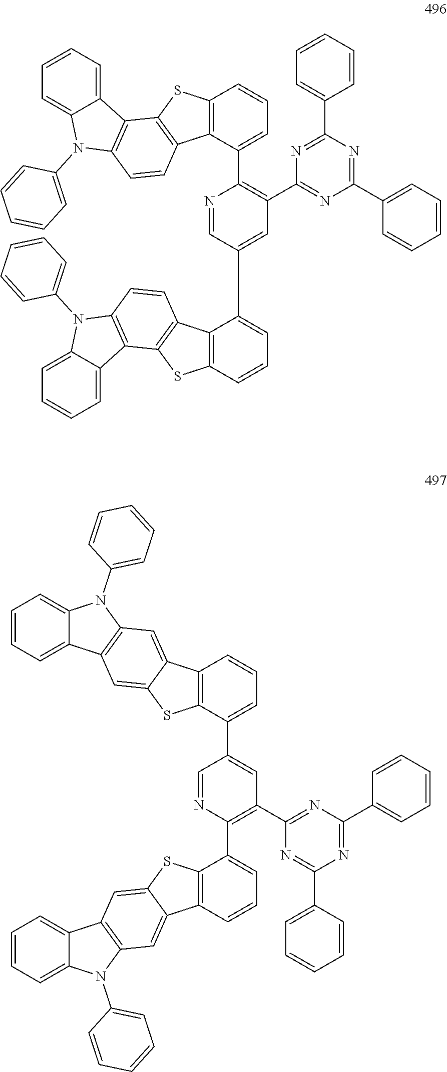 [SMILES: c1ccc(-c2nc(-c3ccccc3)nc(-c3cc(-c4cccc5sc6c(ccc7c6c6ccccc6n7-c6ccccc6)c45)cnc3-c3cccc4sc5c(ccc6c5c5ccccc5n6-c5ccccc5)c34)n2)cc1 ; c1ccc(-c2nc(-c3ccccc3)nc(-c3cc(-c4cccc5c4sc4cc6c7ccccc7n(-c7ccccc7)c6cc45)cnc3-c3cccc4c3sc3cc5c6ccccc6n(-c6ccccc6)c5cc34)n2)cc1]

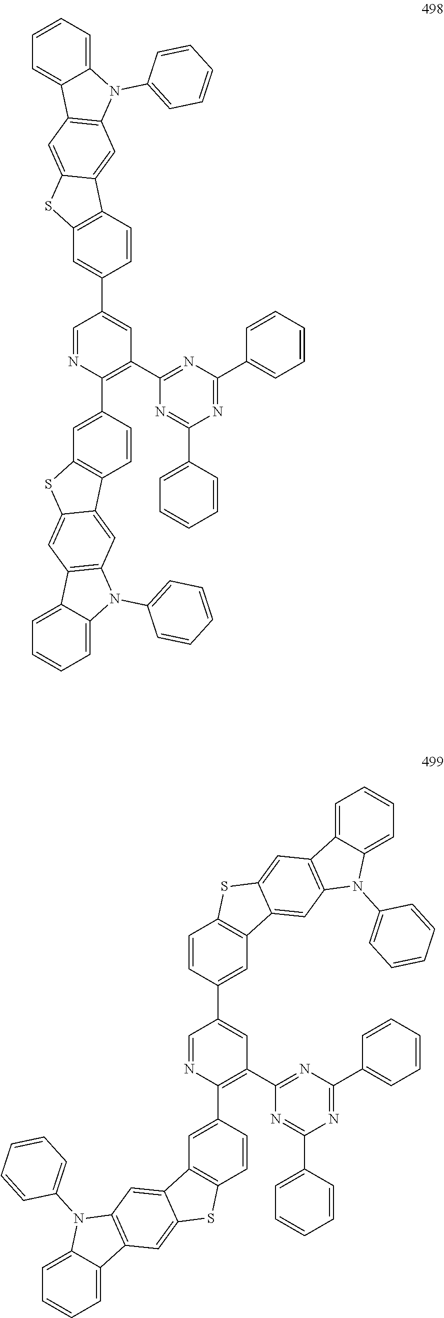 [SMILES: c1ccc(-c2nc(-c3ccccc3)nc(-c3cc(-c4ccc5c(c4)sc4cc6c7ccccc7n(-c7ccccc7)c6cc45)cnc3-c3ccc4c(c3)sc3cc5c6ccccc6n(-c6ccccc6)c5cc34)n2)cc1 ; c1ccc(-c2nc(-c3ccccc3)nc(-c3cc(-c4ccc5sc6cc7c8ccccc8n(-c8ccccc8)c7cc6c5c4)cnc3-c3ccc4sc5cc6c7ccccc7n(-c7ccccc7)c6cc5c4c3)n2)cc1]

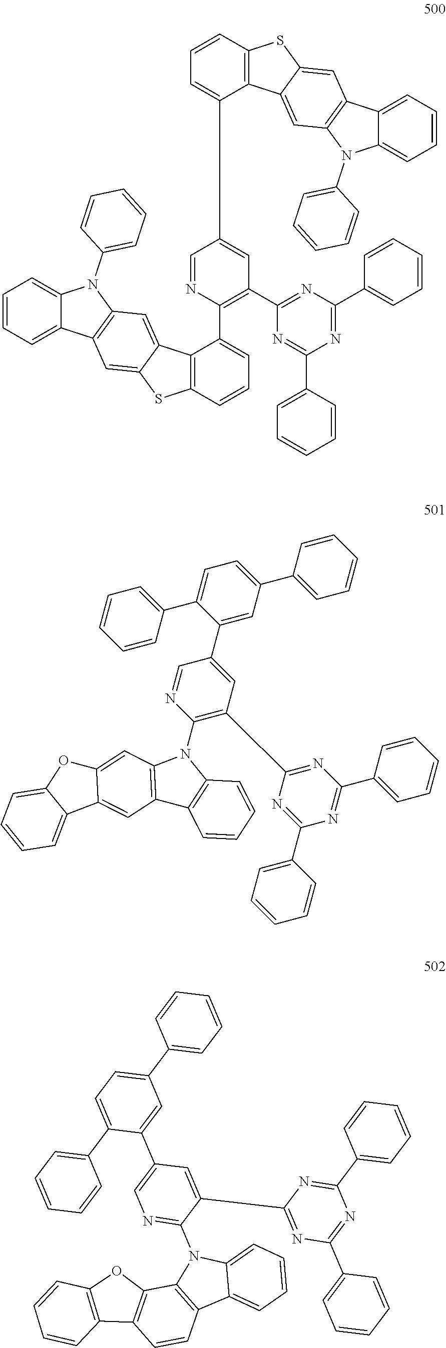 [SMILES: c1ccc(-c2nc(-c3ccccc3)nc(-c3cc(-c4cccc5sc6cc7c8ccccc8n(-c8ccccc8)c7cc6c45)cnc3-c3cccc4sc5cc6c7ccccc7n(-c7ccccc7)c6cc5c34)n2)cc1 ; c1ccc(-c2ccc(-c3ccccc3)c(-c3cnc(-n4c5ccccc5c5cc6c(cc54)oc4ccccc46)c(-c4nc(-c5ccccc5)nc(-c5ccccc5)n4)c3)c2)cc1 ; c1ccc(-c2ccc(-c3ccccc3)c(-c3cnc(-n4c5ccccc5c5ccc6c7ccccc7oc6c54)c(-c4nc(-c5ccccc5)nc(-c5ccccc5)n4)c3)c2)cc1]

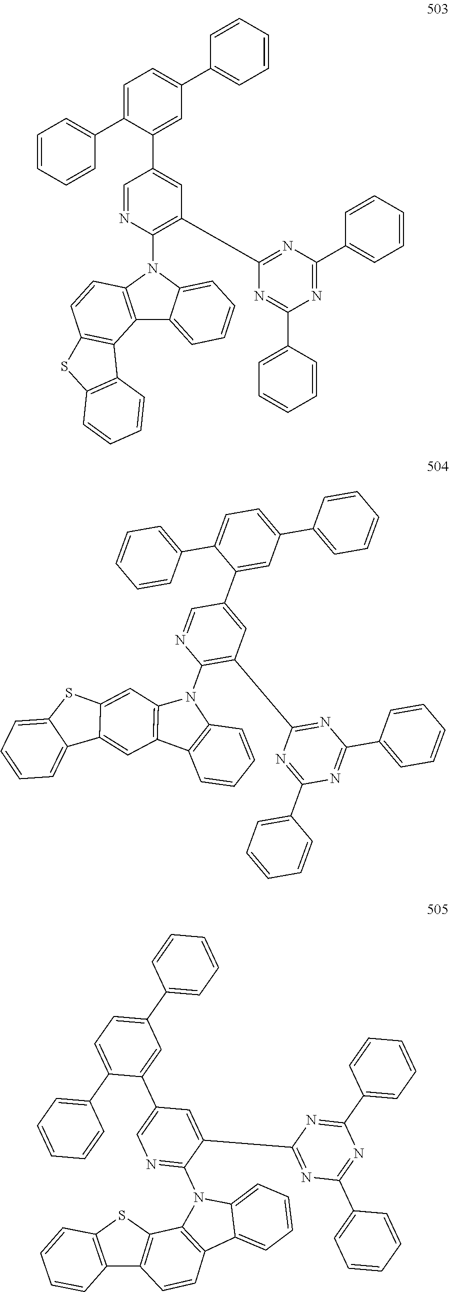 [SMILES: c1ccc(-c2ccc(-c3ccccc3)c(-c3cnc(-n4c5ccccc5c5c6c(ccc54)sc4ccccc46)c(-c4nc(-c5ccccc5)nc(-c5ccccc5)n4)c3)c2)cc1 ; c1ccc(-c2ccc(-c3ccccc3)c(-c3cnc(-n4c5ccccc5c5cc6c(cc54)sc4ccccc46)c(-c4nc(-c5ccccc5)nc(-c5ccccc5)n4)c3)c2)cc1 ; c1ccc(-c2ccc(-c3ccccc3)c(-c3cnc(-n4c5ccccc5c5ccc6c7ccccc7sc6c54)c(-c4nc(-c5ccccc5)nc(-c5ccccc5)n4)c3)c2)cc1]

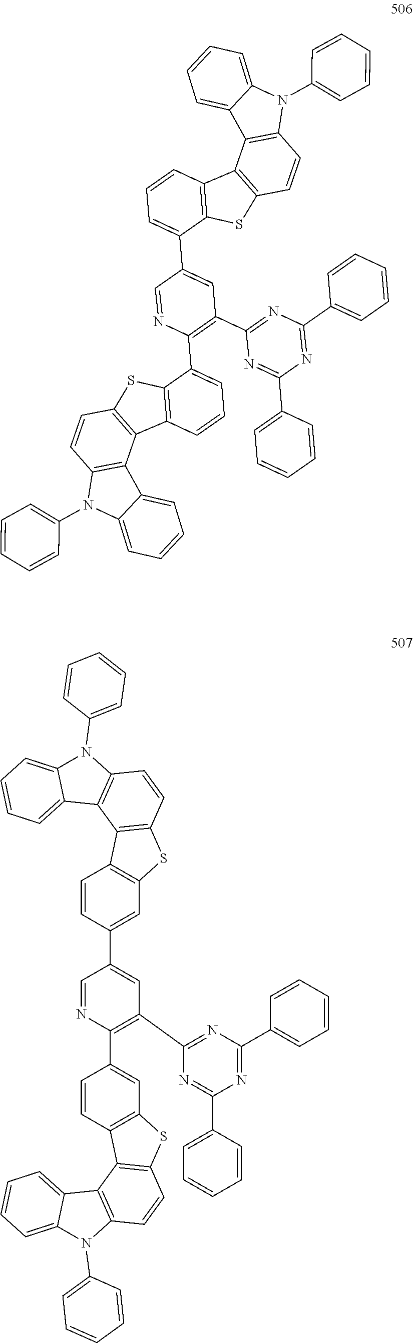 [SMILES: c1ccc(-c2nc(-c3ccccc3)nc(-c3cc(-c4cccc5c4sc4ccc6c(c7ccccc7n6-c6ccccc6)c45)cnc3-c3cccc4c3sc3ccc5c(c6ccccc6n5-c5ccccc5)c34)n2)cc1 ; c1ccc(-c2nc(-c3ccccc3)nc(-c3cc(-c4ccc5c(c4)sc4ccc6c(c7ccccc7n6-c6ccccc6)c45)cnc3-c3ccc4c(c3)sc3ccc5c(c6ccccc6n5-c5ccccc5)c34)n2)cc1]

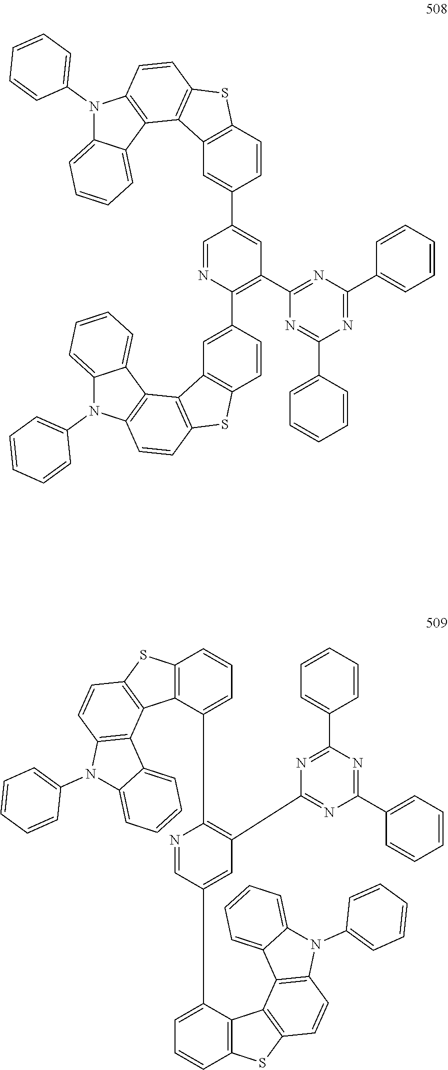 [SMILES: c1ccc(-c2nc(-c3ccccc3)nc(-c3cc(-c4ccc5sc6ccc7c(c8ccccc8n7-c7ccccc7)c6c5c4)cnc3-c3ccc4sc5ccc6c(c7ccccc7n6-c6ccccc6)c5c4c3)n2)cc1 ; c1ccc(-c2nc(-c3ccccc3)nc(-c3cc(-c4cccc5sc6ccc7c(c8ccccc8n7-c7ccccc7)c6c45)cnc3-c3cccc4sc5ccc6c(c7ccccc7n6-c6ccccc6)c5c34)n2)cc1]

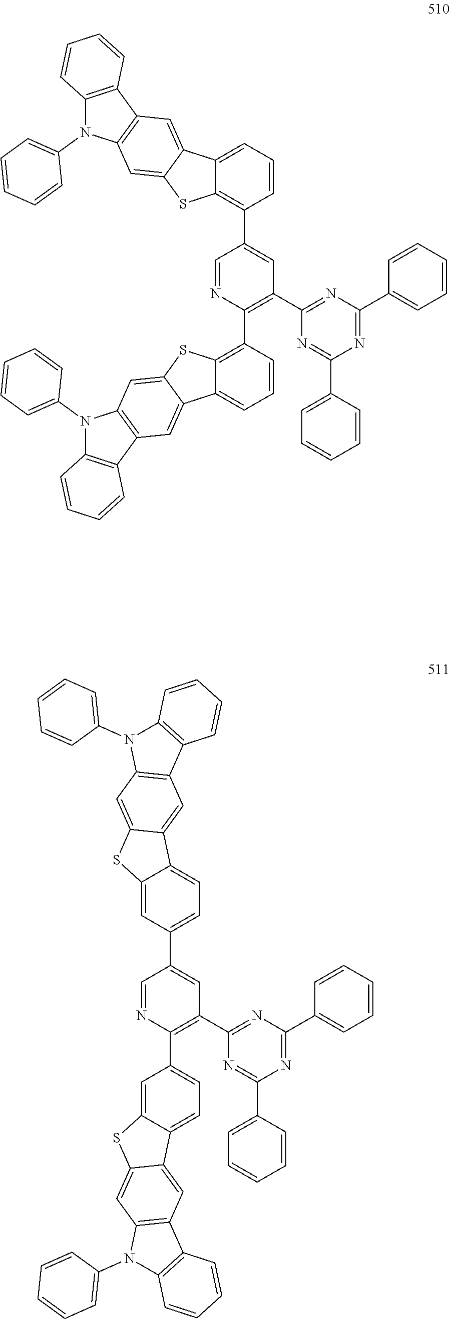 [SMILES: c1ccc(-c2nc(-c3ccccc3)nc(-c3cc(-c4cccc5c4sc4cc6c(cc45)c4ccccc4n6-c4ccccc4)cnc3-c3cccc4c3sc3cc5c(cc34)c3ccccc3n5-c3ccccc3)n2)cc1 ; c1ccc(-c2nc(-c3ccccc3)nc(-c3cc(-c4ccc5c(c4)sc4cc6c(cc45)c4ccccc4n6-c4ccccc4)cnc3-c3ccc4c(c3)sc3cc5c(cc34)c3ccccc3n5-c3ccccc3)n2)cc1]

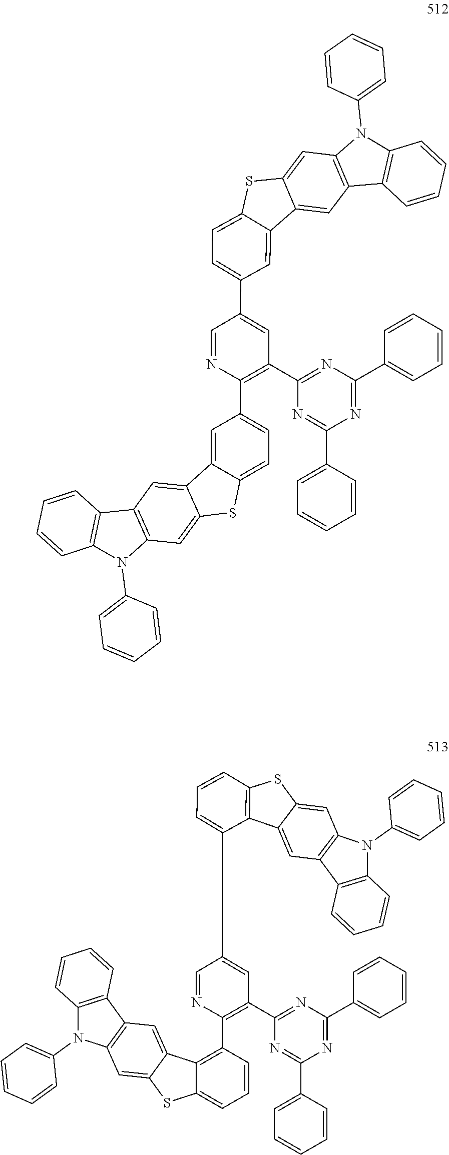 [SMILES: c1ccc(-c2nc(-c3ccccc3)nc(-c3cc(-c4ccc5sc6cc7c(cc6c5c4)c4ccccc4n7-c4ccccc4)cnc3-c3ccc4sc5cc6c(cc5c4c3)c3ccccc3n6-c3ccccc3)n2)cc1 ; c1ccc(-c2nc(-c3ccccc3)nc(-c3cc(-c4cccc5sc6cc7c(cc6c45)c4ccccc4n7-c4ccccc4)cnc3-c3cccc4sc5cc6c(cc5c34)c3ccccc3n6-c3ccccc3)n2)cc1]

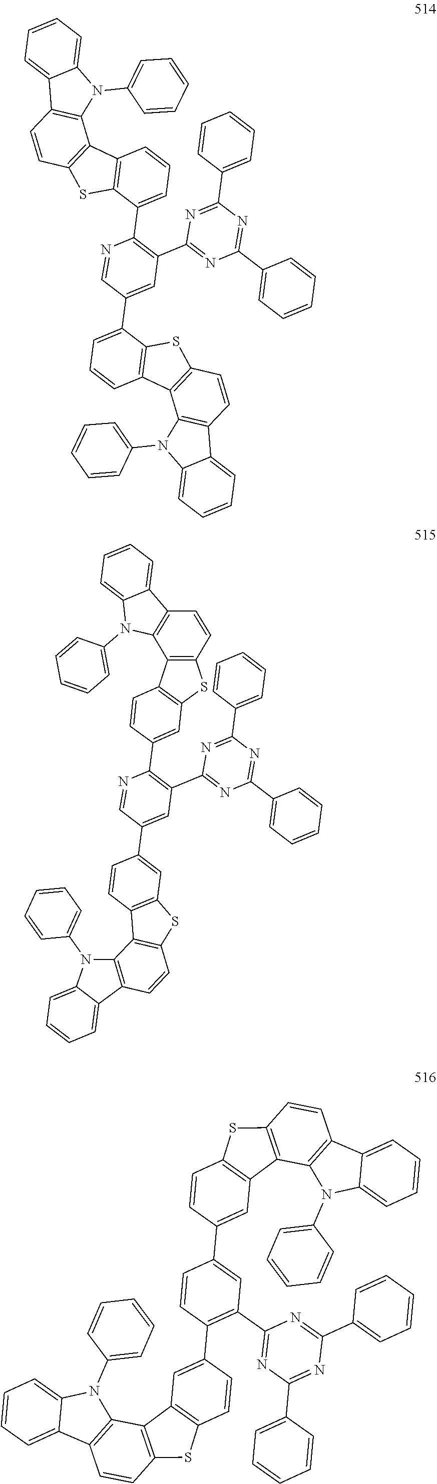 [SMILES: c1ccc(-c2nc(-c3ccccc3)nc(-c3cc(-c4cccc5c4sc4ccc6c7ccccc7n(-c7ccccc7)c6c45)cnc3-c3cccc4c3sc3ccc5c6ccccc6n(-c6ccccc6)c5c34)n2)cc1 ; c1ccc(-c2nc(-c3ccccc3)nc(-c3cc(-c4ccc5c(c4)sc4ccc6c7ccccc7n(-c7ccccc7)c6c45)cnc3-c3ccc4c(c3)sc3ccc5c6ccccc6n(-c6ccccc6)c5c34)n2)cc1 ; c1ccc(-c2nc(-c3ccccc3)nc(-c3cc(-c4ccc5sc6ccc7c8ccccc8n(-c8ccccc8)c7c6c5c4)ccc3-c3ccc4sc5ccc6c7ccccc7n(-c7ccccc7)c6c5c4c3)n2)cc1]

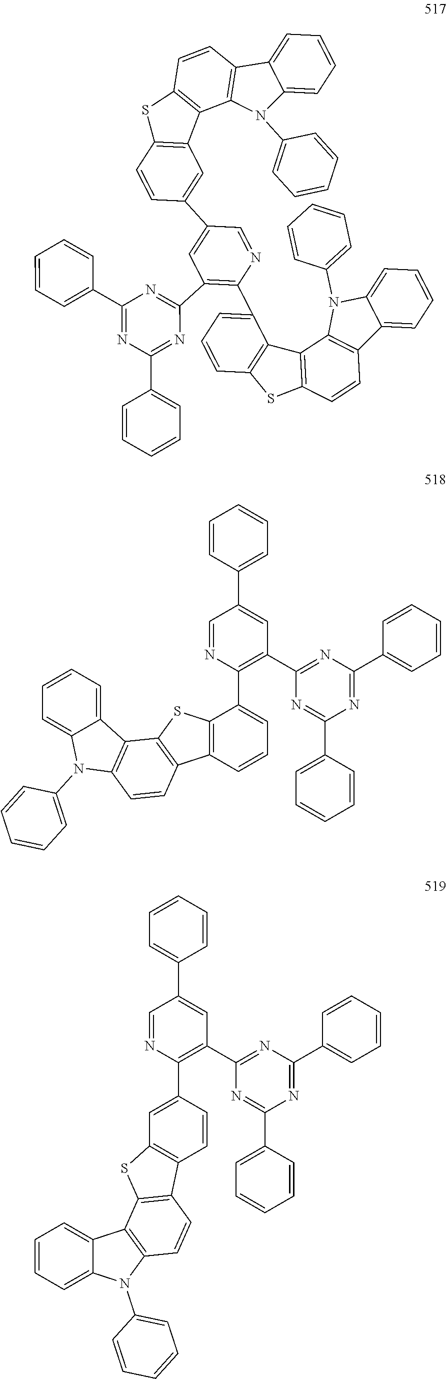 [SMILES: c1ccc(-c2nc(-c3ccccc3)nc(-c3cc(-c4ccc5sc6ccc7c8ccccc8n(-c8ccccc8)c7c6c5c4)cnc3-c3cccc4sc5ccc6c7ccccc7n(-c7ccccc7)c6c5c34)n2)cc1 ; c1ccc(-c2cnc(-c3cccc4c3sc3c4ccc4c3c3ccccc3n4-c3ccccc3)c(-c3nc(-c4ccccc4)nc(-c4ccccc4)n3)c2)cc1 ; c1ccc(-c2cnc(-c3ccc4c(c3)sc3c4ccc4c3c3ccccc3n4-c3ccccc3)c(-c3nc(-c4ccccc4)nc(-c4ccccc4)n3)c2)cc1]

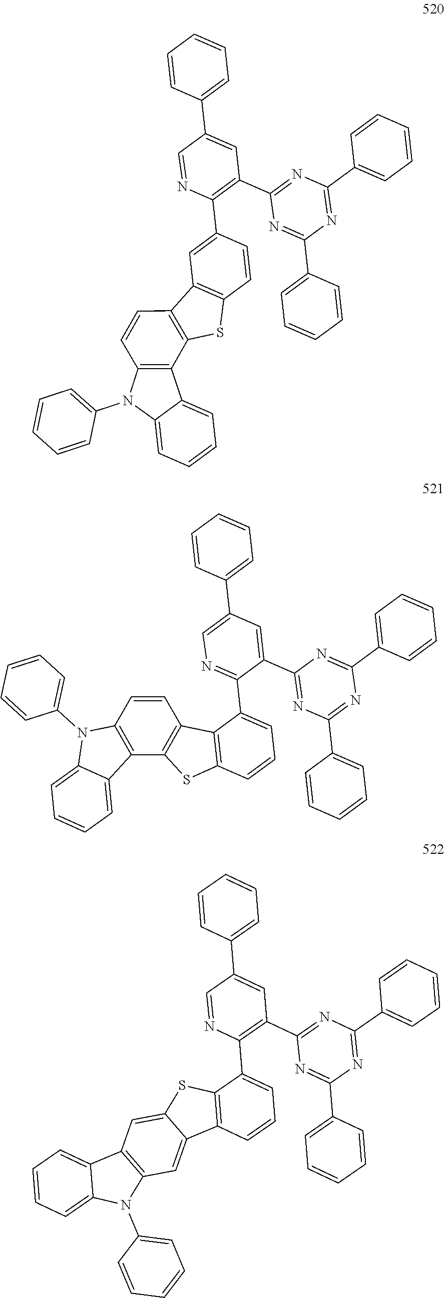 [SMILES: c1ccc(-c2cnc(-c3ccc4sc5c(ccc6c5c5ccccc5n6-c5ccccc5)c4c3)c(-c3nc(-c4ccccc4)nc(-c4ccccc4)n3)c2)cc1 ; c1ccc(-c2cnc(-c3cccc4sc5c(ccc6c5c5ccccc5n6-c5ccccc5)c34)c(-c3nc(-c4ccccc4)nc(-c4ccccc4)n3)c2)cc1 ; c1ccc(-c2cnc(-c3cccc4c3sc3cc5c6ccccc6n(-c6ccccc6)c5cc34)c(-c3nc(-c4ccccc4)nc(-c4ccccc4)n3)c2)cc1]

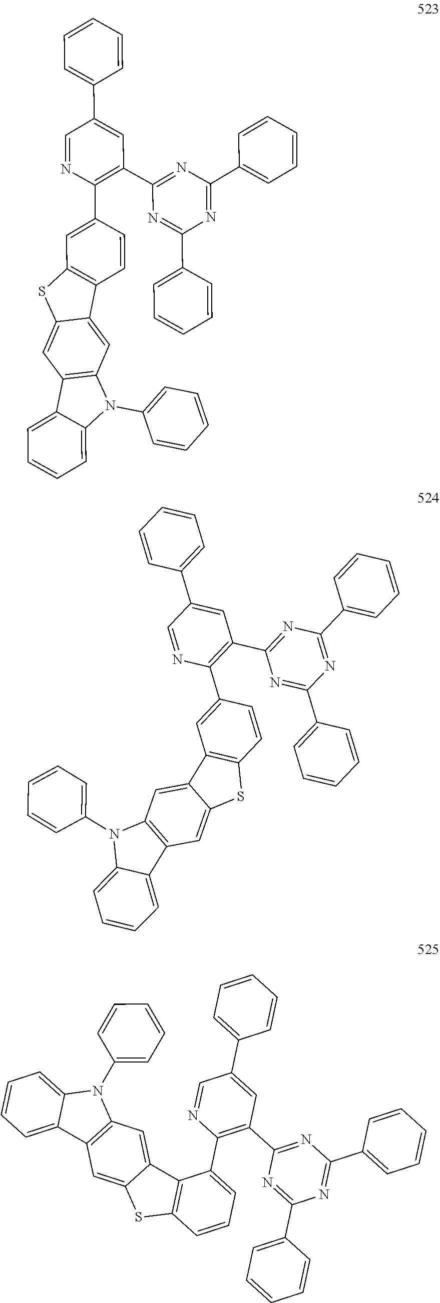 [SMILES: c1ccc(-c2cnc(-c3ccc4c(c3)sc3cc5c6ccccc6n(-c6ccccc6)c5cc34)c(-c3nc(-c4ccccc4)nc(-c4ccccc4)n3)c2)cc1 ; c1ccc(-c2cnc(-c3ccc4sc5cc6c7ccccc7n(-c7ccccc7)c6cc5c4c3)c(-c3nc(-c4ccccc4)nc(-c4ccccc4)n3)c2)cc1 ; c1ccc(-c2cnc(-c3cccc4sc5cc6c7ccccc7n(-c7ccccc7)c6cc5c34)c(-c3nc(-c4ccccc4)nc(-c4ccccc4)n3)c2)cc1]

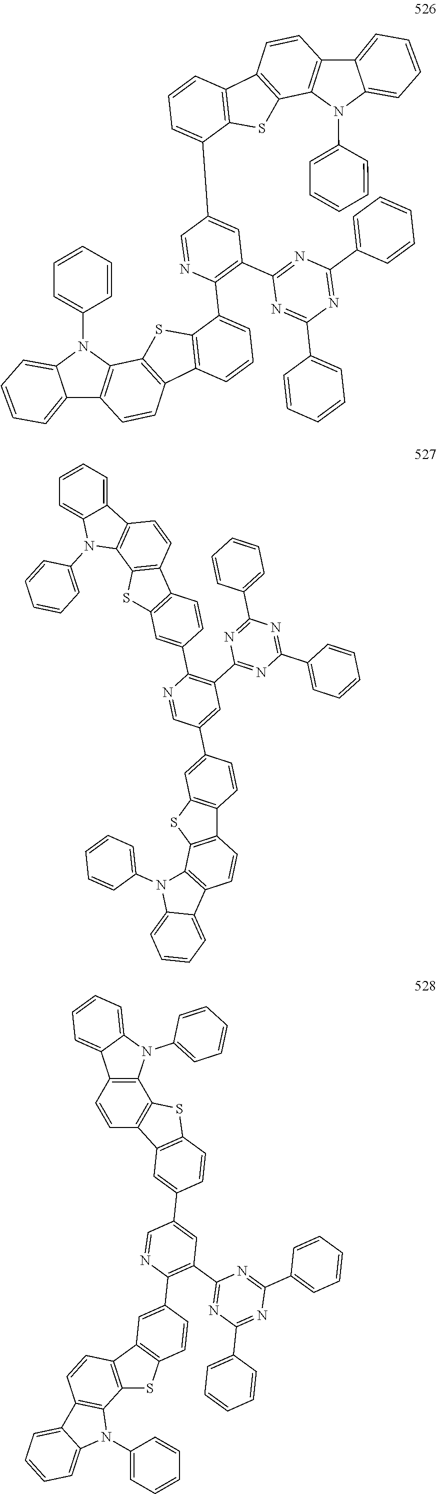 [SMILES: c1ccc(-c2nc(-c3ccccc3)nc(-c3cc(-c4cccc5c4sc4c5ccc5c6ccccc6n(-c6ccccc6)c54)cnc3-c3cccc4c3sc3c4ccc4c5ccccc5n(-c5ccccc5)c43)n2)cc1 ; c1ccc(-c2nc(-c3ccccc3)nc(-c3cc(-c4ccc5c(c4)sc4c5ccc5c6ccccc6n(-c6ccccc6)c54)cnc3-c3ccc4c(c3)sc3c4ccc4c5ccccc5n(-c5ccccc5)c43)n2)cc1 ; c1ccc(-c2nc(-c3ccccc3)nc(-c3cc(-c4ccc5sc6c(ccc7c8ccccc8n(-c8ccccc8)c76)c5c4)cnc3-c3ccc4sc5c(ccc6c7ccccc7n(-c7ccccc7)c65)c4c3)n2)cc1]

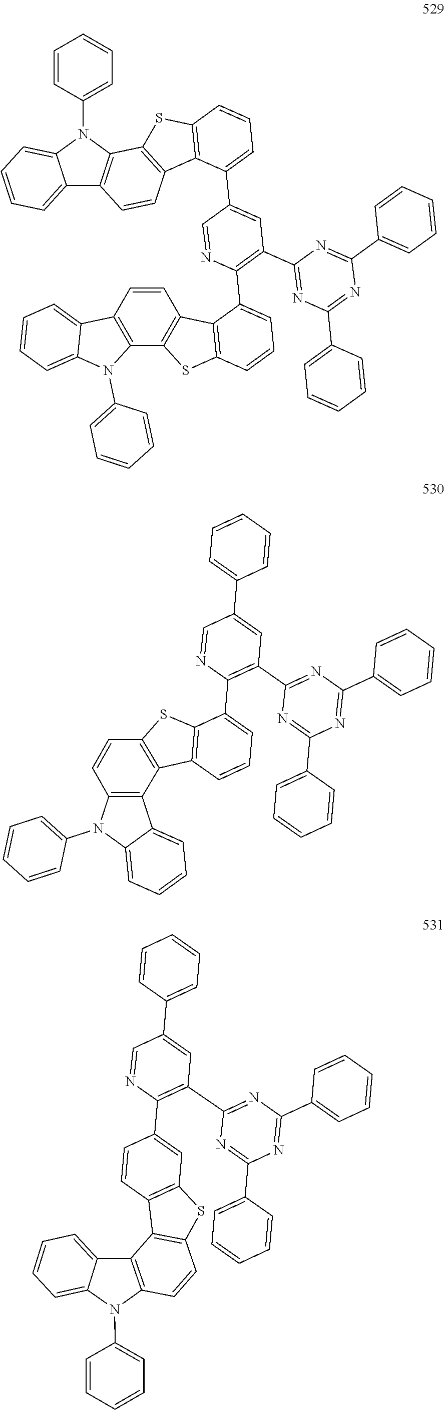

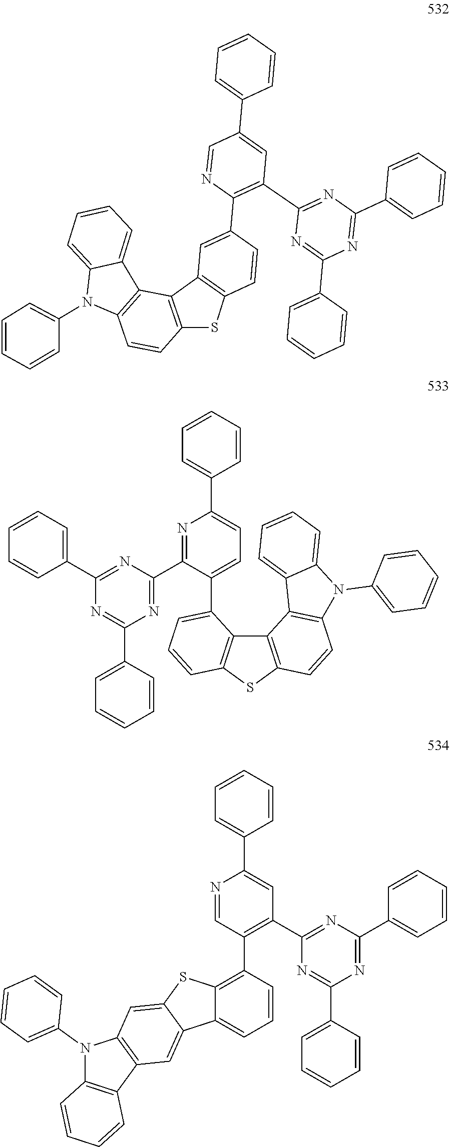 [SMILES: c1ccc(-c2cnc(-c3ccc4sc5ccc6c(c7ccccc7n6-c6ccccc6)c5c4c3)c(-c3nc(-c4ccccc4)nc(-c4ccccc4)n3)c2)cc1 ; c1ccc(-c2ccc(-c3cccc4sc5ccc6c(c7ccccc7n6-c6ccccc6)c5c34)c(-c3nc(-c4ccccc4)nc(-c4ccccc4)n3)n2)cc1 ; c1ccc(-c2cc(-c3nc(-c4ccccc4)nc(-c4ccccc4)n3)c(-c3cccc4c3sc3cc5c(cc34)c3ccccc3n5-c3ccccc3)cn2)cc1]

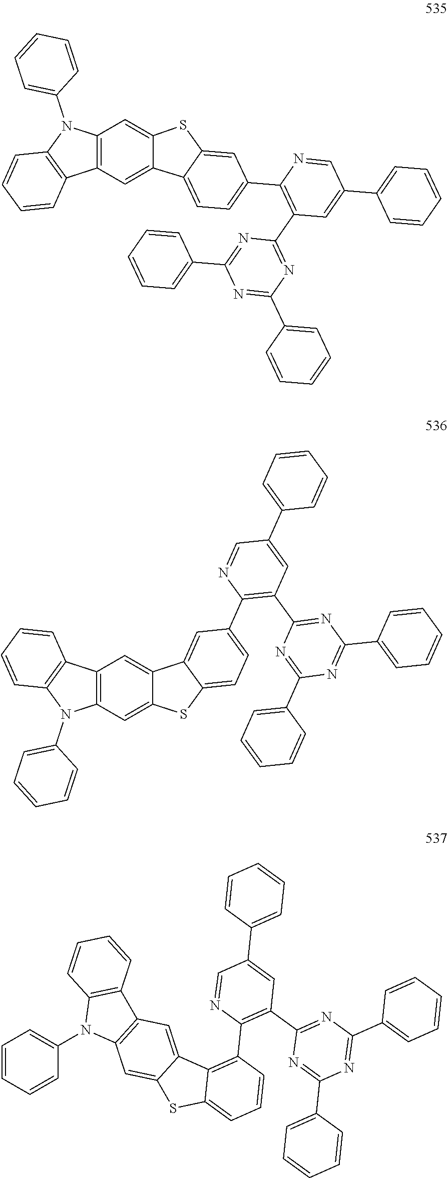 [SMILES: c1ccc(-c2cnc(-c3ccc4c(c3)sc3cc5c(cc34)c3ccccc3n5-c3ccccc3)c(-c3nc(-c4ccccc4)nc(-c4ccccc4)n3)c2)cc1 ; c1ccc(-c2cnc(-c3ccc4sc5cc6c(cc5c4c3)c3ccccc3n6-c3ccccc3)c(-c3nc(-c4ccccc4)nc(-c4ccccc4)n3)c2)cc1 ; c1ccc(-c2cnc(-c3cccc4sc5cc6c(cc5c34)c3ccccc3n6-c3ccccc3)c(-c3nc(-c4ccccc4)nc(-c4ccccc4)n3)c2)cc1]

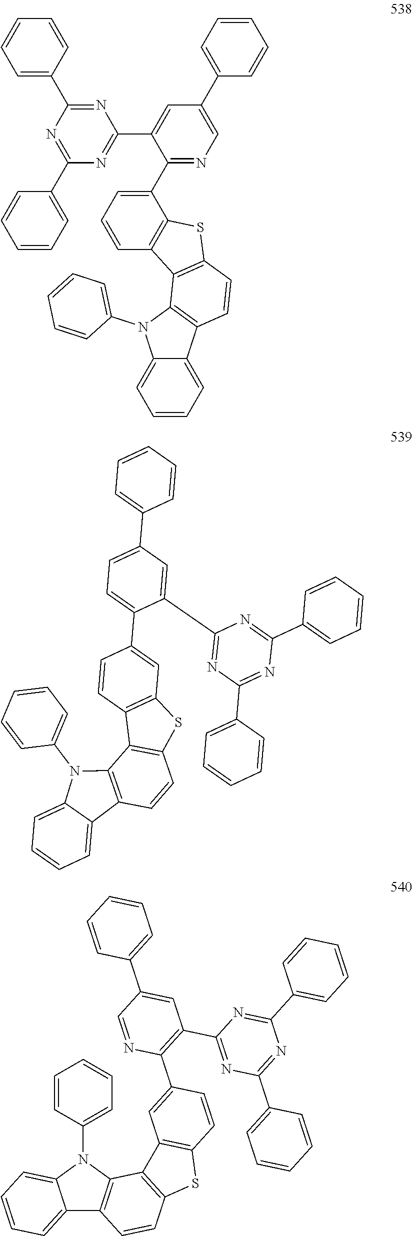

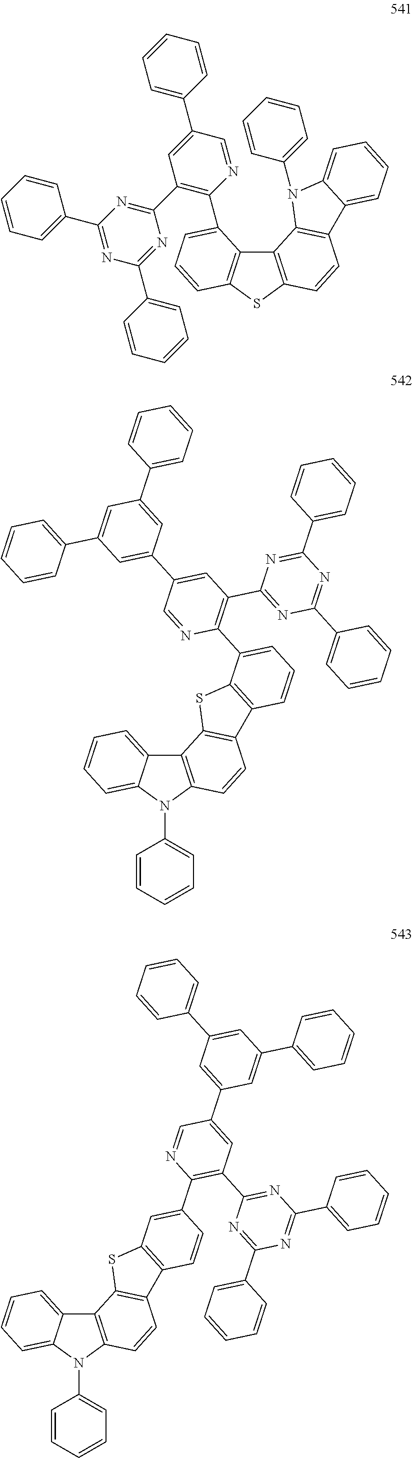

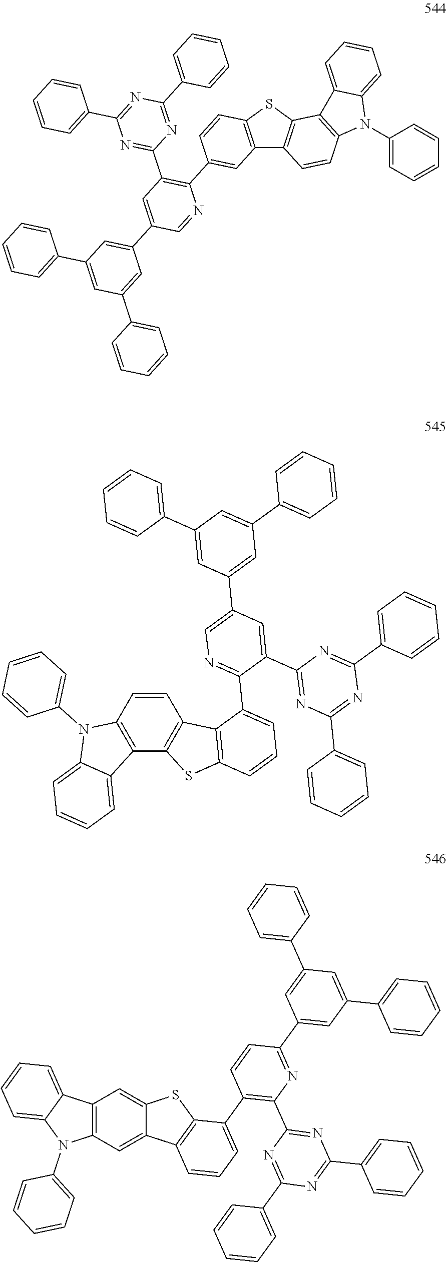 [SMILES: c1ccc(-c2cc(-c3ccccc3)cc(-c3cnc(-c4ccc5sc6c(ccc7c6c6ccccc6n7-c6ccccc6)c5c4)c(-c4nc(-c5ccccc5)nc(-c5ccccc5)n4)c3)c2)cc1 ; c1ccc(-c2cc(-c3ccccc3)cc(-c3cnc(-c4cccc5sc6c(ccc7c6c6ccccc6n7-c6ccccc6)c45)c(-c4nc(-c5ccccc5)nc(-c5ccccc5)n4)c3)c2)cc1 ; c1ccc(-c2cc(-c3ccccc3)cc(-c3ccc(-c4cccc5c4sc4cc6c7ccccc7n(-c7ccccc7)c6cc45)c(-c4nc(-c5ccccc5)nc(-c5ccccc5)n4)n3)c2)cc1]

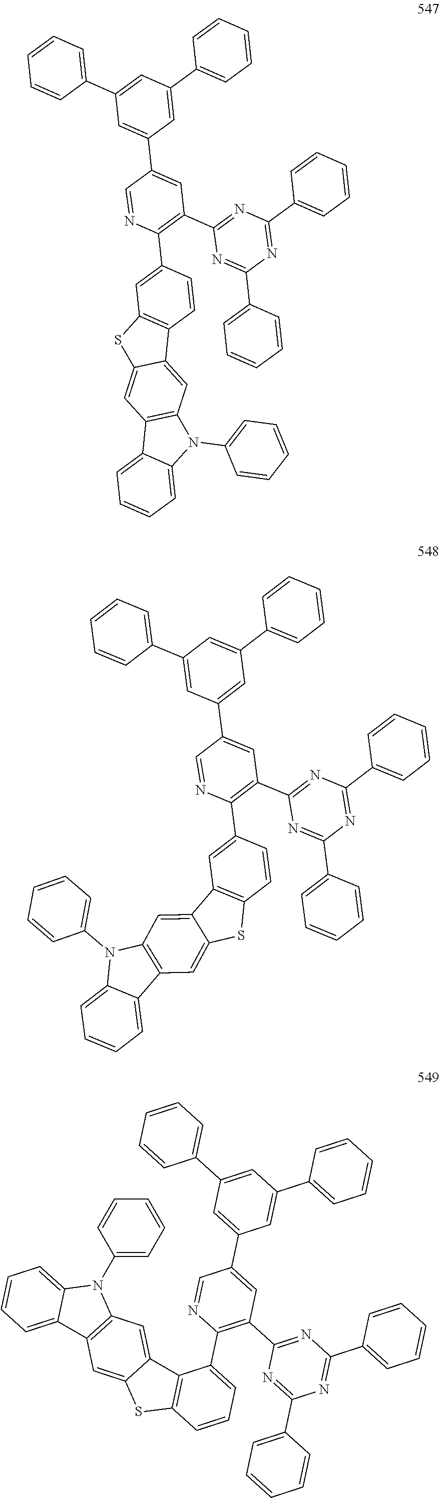 [SMILES: c1ccc(-c2cc(-c3ccccc3)cc(-c3cnc(-c4ccc5c(c4)sc4cc6c7ccccc7n(-c7ccccc7)c6cc45)c(-c4nc(-c5ccccc5)nc(-c5ccccc5)n4)c3)c2)cc1 ; c1ccc(-c2cc(-c3ccccc3)cc(-c3cnc(-c4ccc5sc6cc7c8ccccc8n(-c8ccccc8)c7cc6c5c4)c(-c4nc(-c5ccccc5)nc(-c5ccccc5)n4)c3)c2)cc1 ; c1ccc(-c2cc(-c3ccccc3)cc(-c3cnc(-c4cccc5sc6cc7c8ccccc8n(-c8ccccc8)c7cc6c45)c(-c4nc(-c5ccccc5)nc(-c5ccccc5)n4)c3)c2)cc1]

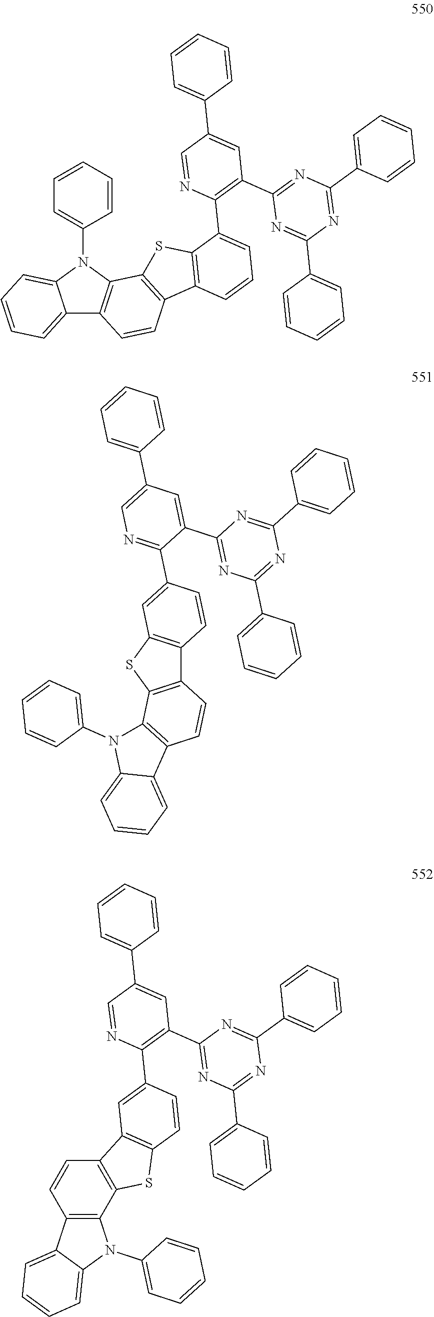 [SMILES: c1ccc(-c2cnc(-c3cccc4c3sc3c4ccc4c5ccccc5n(-c5ccccc5)c43)c(-c3nc(-c4ccccc4)nc(-c4ccccc4)n3)c2)cc1 ; c1ccc(-c2cnc(-c3ccc4c(c3)sc3c4ccc4c5ccccc5n(-c5ccccc5)c43)c(-c3nc(-c4ccccc4)nc(-c4ccccc4)n3)c2)cc1 ; c1ccc(-c2cnc(-c3ccc4sc5c(ccc6c7ccccc7n(-c7ccccc7)c65)c4c3)c(-c3nc(-c4ccccc4)nc(-c4ccccc4)n3)c2)cc1]

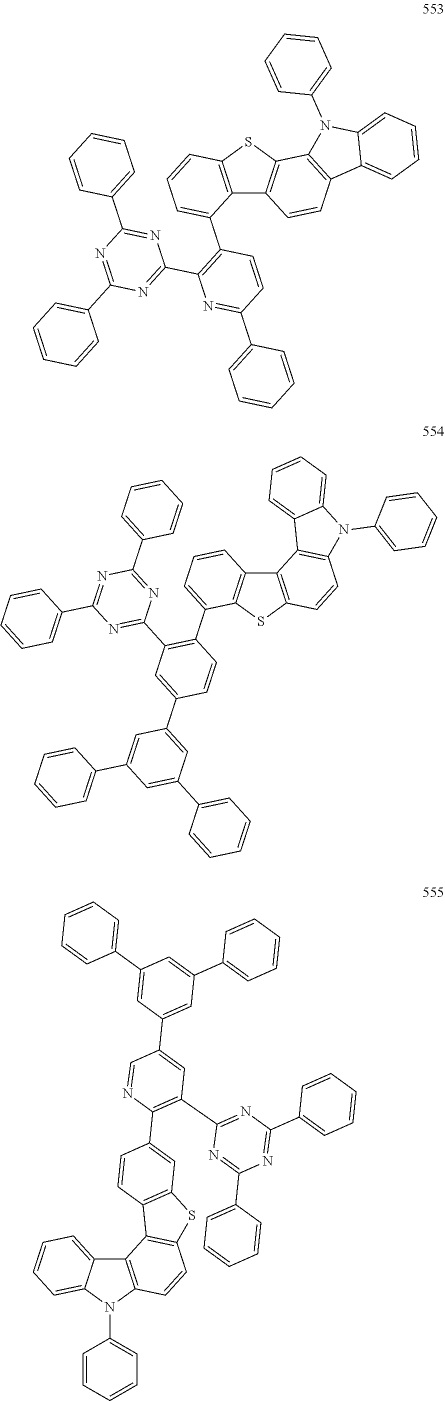 [SMILES: c1ccc(-c2ccc(-c3cccc4sc5c(ccc6c7ccccc7n(-c7ccccc7)c65)c34)c(-c3nc(-c4ccccc4)nc(-c4ccccc4)n3)n2)cc1 ; c1ccc(-c2cc(-c3ccccc3)cc(-c3ccc(-c4cccc5c4sc4ccc6c(c7ccccc7n6-c6ccccc6)c45)c(-c4nc(-c5ccccc5)nc(-c5ccccc5)n4)c3)c2)cc1 ; c1ccc(-c2cc(-c3ccccc3)cc(-c3cnc(-c4ccc5c(c4)sc4ccc6c(c7ccccc7n6-c6ccccc6)c45)c(-c4nc(-c5ccccc5)nc(-c5ccccc5)n4)c3)c2)cc1]

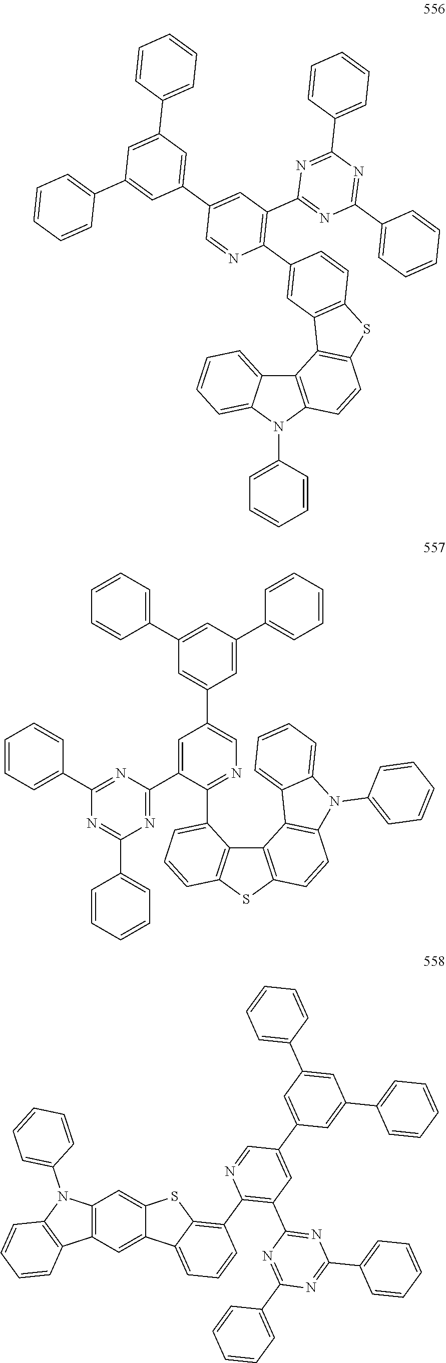 [SMILES: c1ccc(-c2cc(-c3ccccc3)cc(-c3cnc(-c4ccc5sc6ccc7c(c8ccccc8n7-c7ccccc7)c6c5c4)c(-c4nc(-c5ccccc5)nc(-c5ccccc5)n4)c3)c2)cc1 ; c1ccc(-c2cc(-c3ccccc3)cc(-c3cnc(-c4cccc5sc6ccc7c(c8ccccc8n7-c7ccccc7)c6c45)c(-c4nc(-c5ccccc5)nc(-c5ccccc5)n4)c3)c2)cc1 ; c1ccc(-c2cc(-c3ccccc3)cc(-c3cnc(-c4cccc5c4sc4cc6c(cc45)c4ccccc4n6-c4ccccc4)c(-c4nc(-c5ccccc5)nc(-c5ccccc5)n4)c3)c2)cc1]

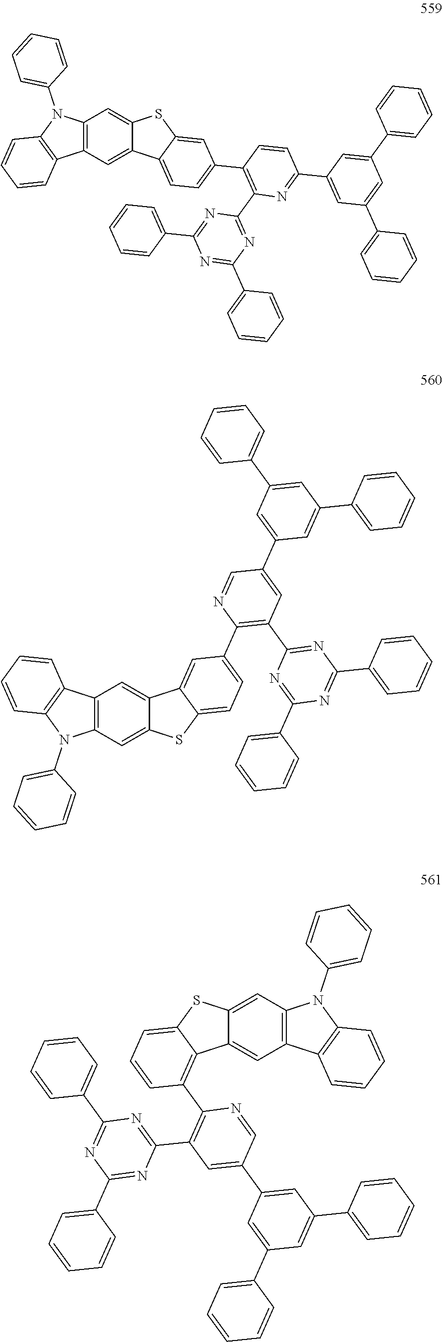 [SMILES: c1ccc(-c2cc(-c3ccccc3)cc(-c3ccc(-c4ccc5c(c4)sc4cc6c(cc45)c4ccccc4n6-c4ccccc4)c(-c4nc(-c5ccccc5)nc(-c5ccccc5)n4)n3)c2)cc1 ; c1ccc(-c2cc(-c3ccccc3)cc(-c3cnc(-c4ccc5sc6cc7c(cc6c5c4)c4ccccc4n7-c4ccccc4)c(-c4nc(-c5ccccc5)nc(-c5ccccc5)n4)c3)c2)cc1 ; c1ccc(-c2cc(-c3ccccc3)cc(-c3cnc(-c4cccc5sc6cc7c(cc6c45)c4ccccc4n7-c4ccccc4)c(-c4nc(-c5ccccc5)nc(-c5ccccc5)n4)c3)c2)cc1]

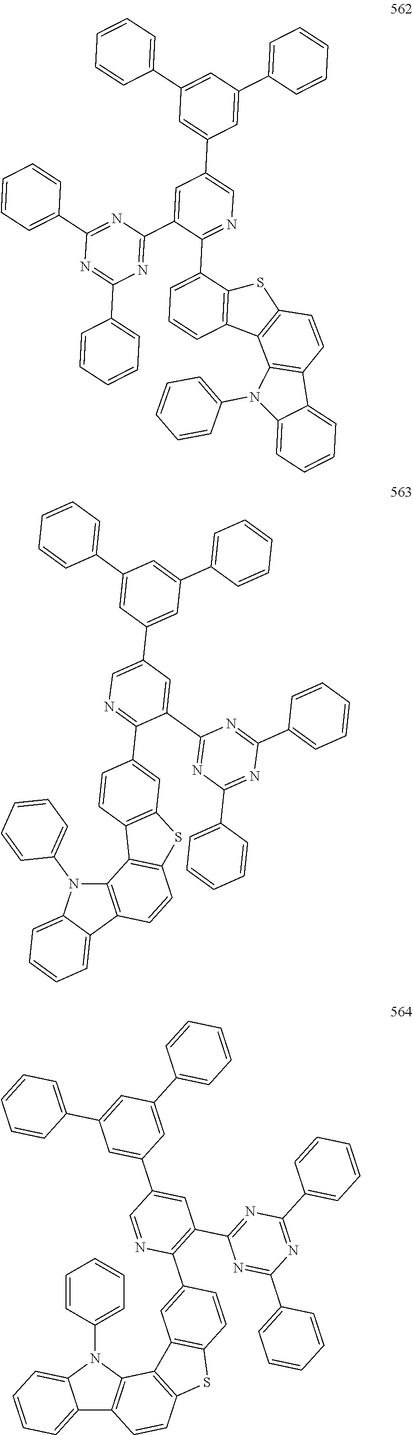 [SMILES: c1ccc(-c2cc(-c3ccccc3)cc(-c3cnc(-c4cccc5c4sc4ccc6c7ccccc7n(-c7ccccc7)c6c45)c(-c4nc(-c5ccccc5)nc(-c5ccccc5)n4)c3)c2)cc1 ; c1ccc(-c2cc(-c3ccccc3)cc(-c3cnc(-c4ccc5c(c4)sc4ccc6c7ccccc7n(-c7ccccc7)c6c45)c(-c4nc(-c5ccccc5)nc(-c5ccccc5)n4)c3)c2)cc1 ; c1ccc(-c2cc(-c3ccccc3)cc(-c3cnc(-c4ccc5sc6ccc7c8ccccc8n(-c8ccccc8)c7c6c5c4)c(-c4nc(-c5ccccc5)nc(-c5ccccc5)n4)c3)c2)cc1]

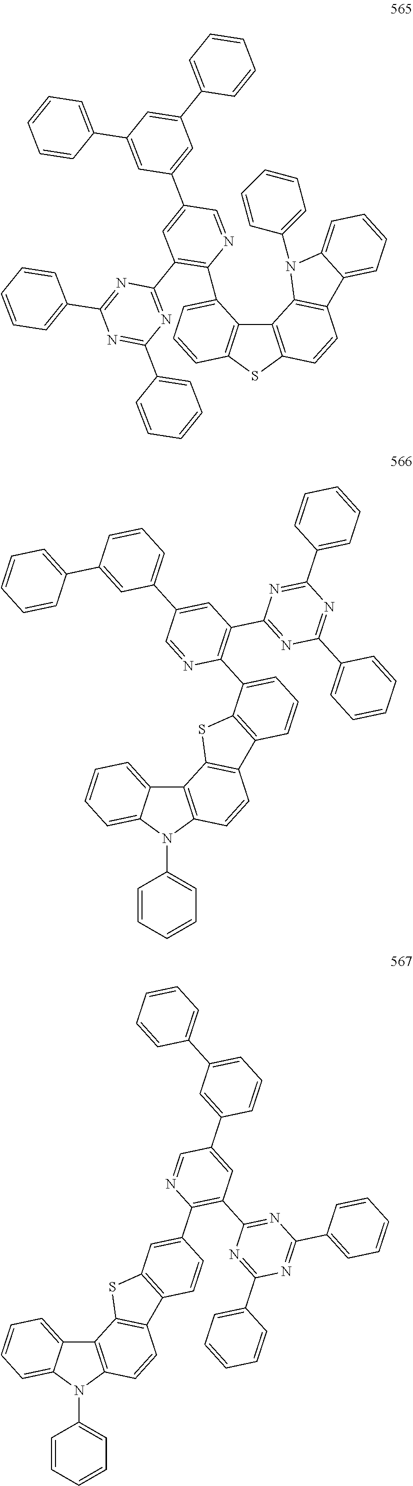 [SMILES: c1ccc(-c2cc(-c3ccccc3)cc(-c3cnc(-c4cccc5sc6ccc7c8ccccc8n(-c8ccccc8)c7c6c45)c(-c4nc(-c5ccccc5)nc(-c5ccccc5)n4)c3)c2)cc1 ; c1ccc(-c2cccc(-c3cnc(-c4cccc5c4sc4c5ccc5c4c4ccccc4n5-c4ccccc4)c(-c4nc(-c5ccccc5)nc(-c5ccccc5)n4)c3)c2)cc1 ; c1ccc(-c2cccc(-c3cnc(-c4ccc5c(c4)sc4c5ccc5c4c4ccccc4n5-c4ccccc4)c(-c4nc(-c5ccccc5)nc(-c5ccccc5)n4)c3)c2)cc1]

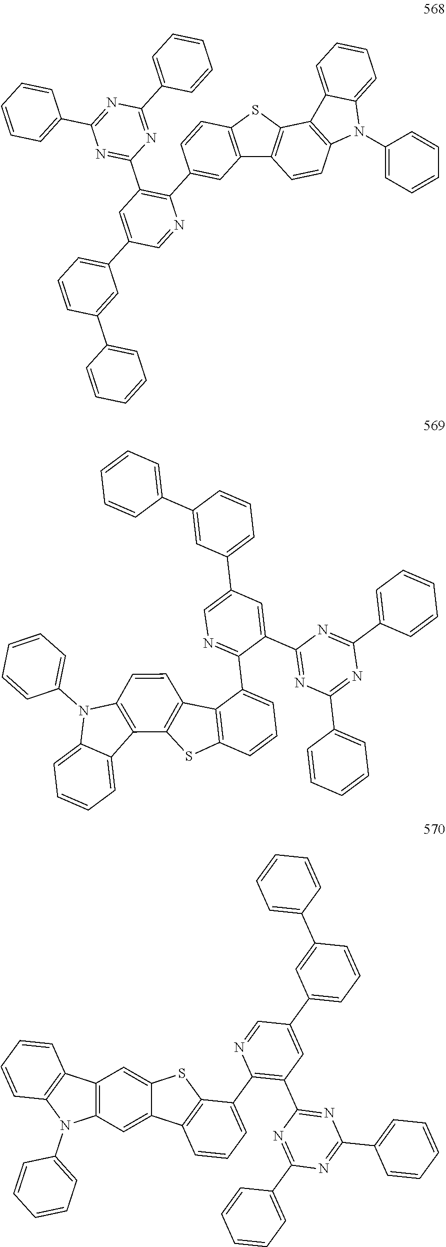 [SMILES: c1ccc(-c2cccc(-c3cnc(-c4ccc5sc6c(ccc7c6c6ccccc6n7-c6ccccc6)c5c4)c(-c4nc(-c5ccccc5)nc(-c5ccccc5)n4)c3)c2)cc1 ; c1ccc(-c2cccc(-c3cnc(-c4cccc5sc6c(ccc7c6c6ccccc6n7-c6ccccc6)c45)c(-c4nc(-c5ccccc5)nc(-c5ccccc5)n4)c3)c2)cc1 ; c1ccc(-c2cccc(-c3cnc(-c4cccc5c4sc4cc6c7ccccc7n(-c7ccccc7)c6cc45)c(-c4nc(-c5ccccc5)nc(-c5ccccc5)n4)c3)c2)cc1]

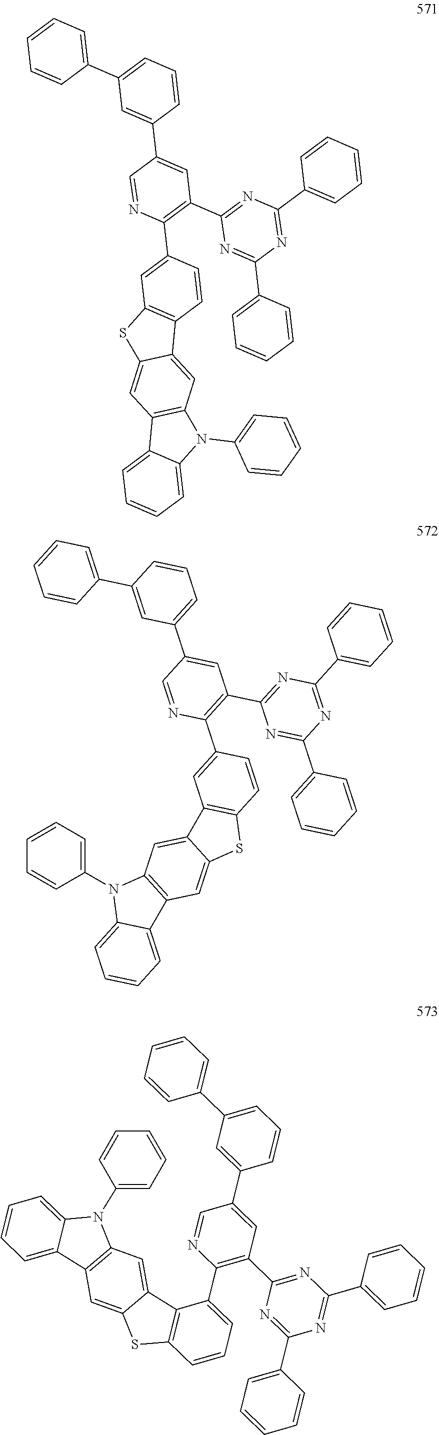

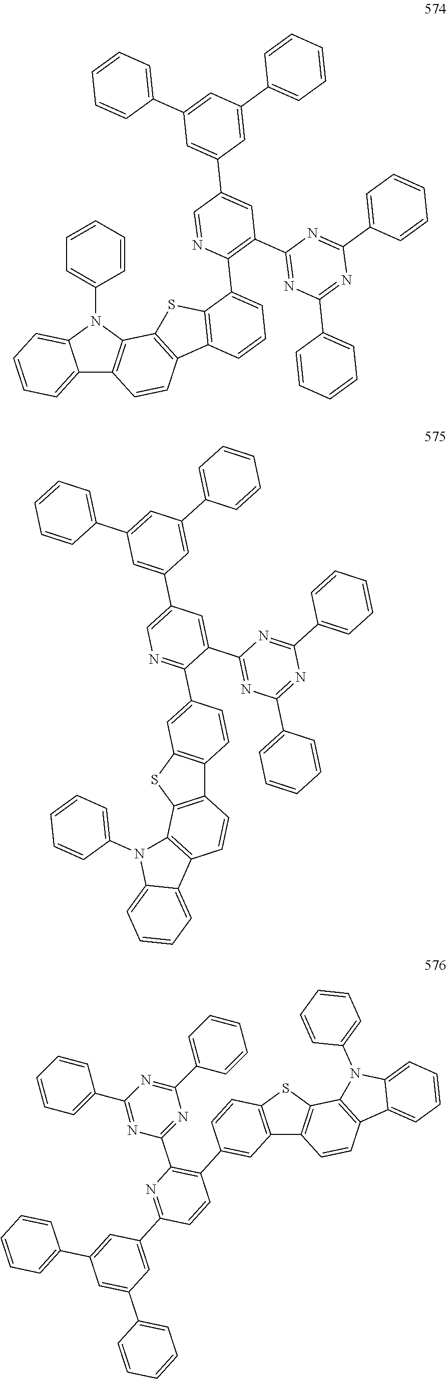 [SMILES: c1ccc(-c2cc(-c3ccccc3)cc(-c3cnc(-c4cccc5c4sc4c5ccc5c6ccccc6n(-c6ccccc6)c54)c(-c4nc(-c5ccccc5)nc(-c5ccccc5)n4)c3)c2)cc1 ; c1ccc(-c2cc(-c3ccccc3)cc(-c3cnc(-c4ccc5c(c4)sc4c5ccc5c6ccccc6n(-c6ccccc6)c54)c(-c4nc(-c5ccccc5)nc(-c5ccccc5)n4)c3)c2)cc1 ; c1ccc(-c2cc(-c3ccccc3)cc(-c3ccc(-c4ccc5sc6c(ccc7c8ccccc8n(-c8ccccc8)c76)c5c4)c(-c4nc(-c5ccccc5)nc(-c5ccccc5)n4)n3)c2)cc1]

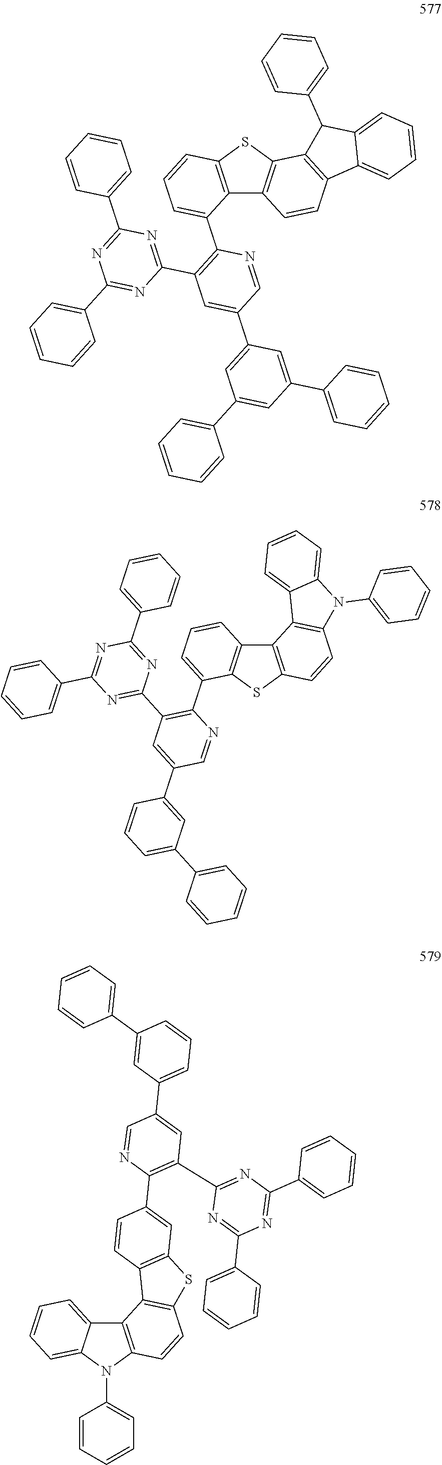 [SMILES: c1ccc(-c2cc(-c3ccccc3)cc(-c3cnc(-c4cccc5sc6c7c(ccc6c45)-c4ccccc4C7c4ccccc4)c(-c4nc(-c5ccccc5)nc(-c5ccccc5)n4)c3)c2)cc1 ; c1ccc(-c2cccc(-c3cnc(-c4cccc5c4sc4ccc6c(c7ccccc7n6-c6ccccc6)c45)c(-c4nc(-c5ccccc5)nc(-c5ccccc5)n4)c3)c2)cc1 ; c1ccc(-c2cccc(-c3cnc(-c4ccc5c(c4)sc4ccc6c(c7ccccc7n6-c6ccccc6)c45)c(-c4nc(-c5ccccc5)nc(-c5ccccc5)n4)c3)c2)cc1]

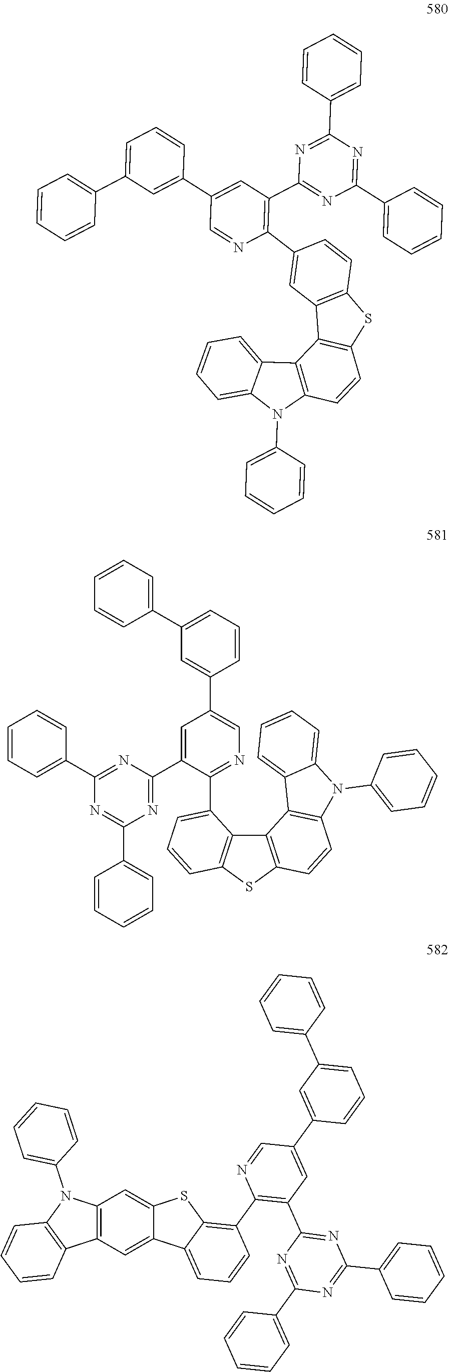 [SMILES: c1ccc(-c2cccc(-c3cnc(-c4ccc5sc6ccc7c(c8ccccc8n7-c7ccccc7)c6c5c4)c(-c4nc(-c5ccccc5)nc(-c5ccccc5)n4)c3)c2)cc1 ; c1ccc(-c2cccc(-c3cnc(-c4cccc5sc6ccc7c(c8ccccc8n7-c7ccccc7)c6c45)c(-c4nc(-c5ccccc5)nc(-c5ccccc5)n4)c3)c2)cc1 ; c1ccc(-c2cccc(-c3cnc(-c4cccc5c4sc4cc6c(cc45)c4ccccc4n6-c4ccccc4)c(-c4nc(-c5ccccc5)nc(-c5ccccc5)n4)c3)c2)cc1]

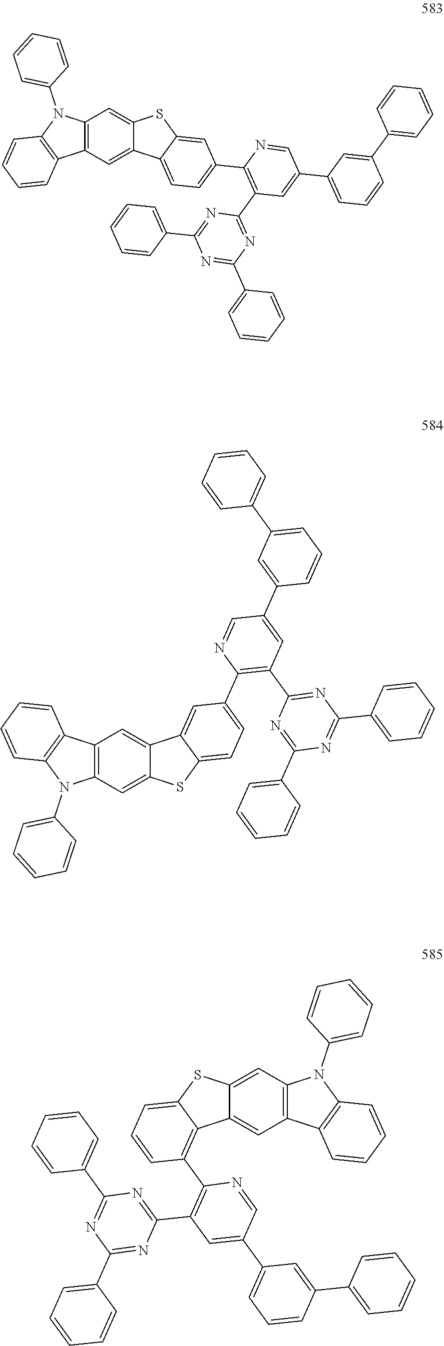 [SMILES: c1ccc(-c2cccc(-c3cnc(-c4ccc5c(c4)sc4cc6c(cc45)c4ccccc4n6-c4ccccc4)c(-c4nc(-c5ccccc5)nc(-c5ccccc5)n4)c3)c2)cc1 ; c1ccc(-c2cccc(-c3cnc(-c4ccc5sc6cc7c(cc6c5c4)c4ccccc4n7-c4ccccc4)c(-c4nc(-c5ccccc5)nc(-c5ccccc5)n4)c3)c2)cc1 ; c1ccc(-c2cccc(-c3cnc(-c4cccc5sc6cc7c(cc6c45)c4ccccc4n7-c4ccccc4)c(-c4nc(-c5ccccc5)nc(-c5ccccc5)n4)c3)c2)cc1]

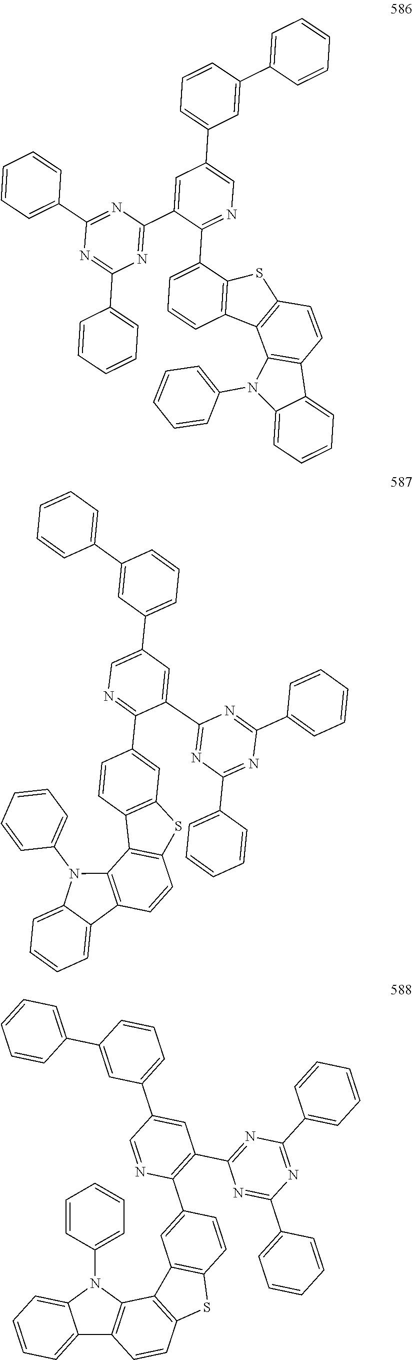

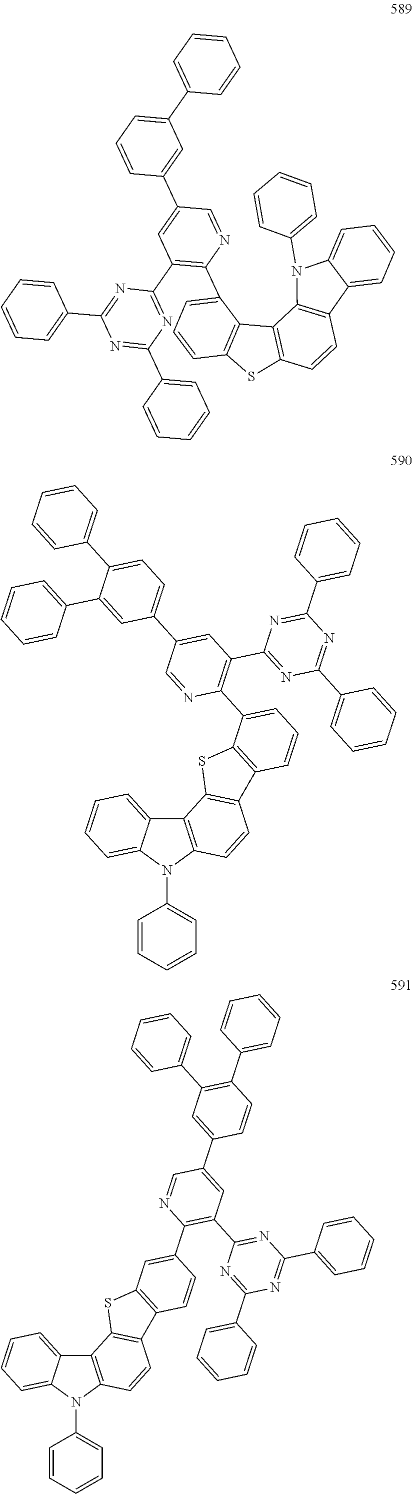

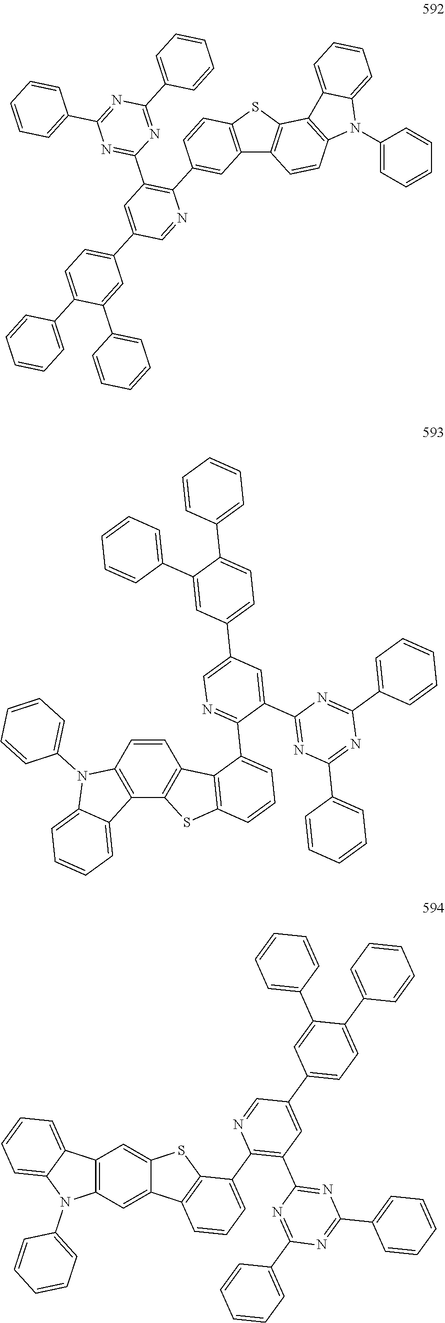 [SMILES: c1ccc(-c2nc(-c3ccccc3)nc(-c3cc(-c4ccc(-c5ccccc5)c(-c5ccccc5)c4)cnc3-c3ccc4sc5c(ccc6c5c5ccccc5n6-c5ccccc5)c4c3)n2)cc1 ; c1ccc(-c2nc(-c3ccccc3)nc(-c3cc(-c4ccc(-c5ccccc5)c(-c5ccccc5)c4)cnc3-c3cccc4sc5c(ccc6c5c5ccccc5n6-c5ccccc5)c34)n2)cc1 ; c1ccc(-c2nc(-c3ccccc3)nc(-c3cc(-c4ccc(-c5ccccc5)c(-c5ccccc5)c4)cnc3-c3cccc4c3sc3cc5c6ccccc6n(-c6ccccc6)c5cc34)n2)cc1]

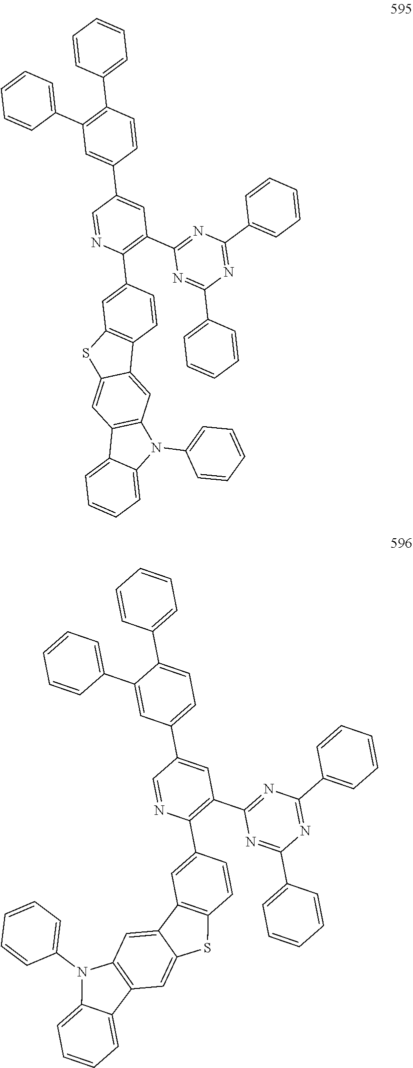 [SMILES: c1ccc(-c2nc(-c3ccccc3)nc(-c3cc(-c4ccc(-c5ccccc5)c(-c5ccccc5)c4)cnc3-c3ccc4c(c3)sc3cc5c6ccccc6n(-c6ccccc6)c5cc34)n2)cc1 ; c1ccc(-c2nc(-c3ccccc3)nc(-c3cc(-c4ccc(-c5ccccc5)c(-c5ccccc5)c4)cnc3-c3ccc4sc5cc6c7ccccc7n(-c7ccccc7)c6cc5c4c3)n2)cc1]

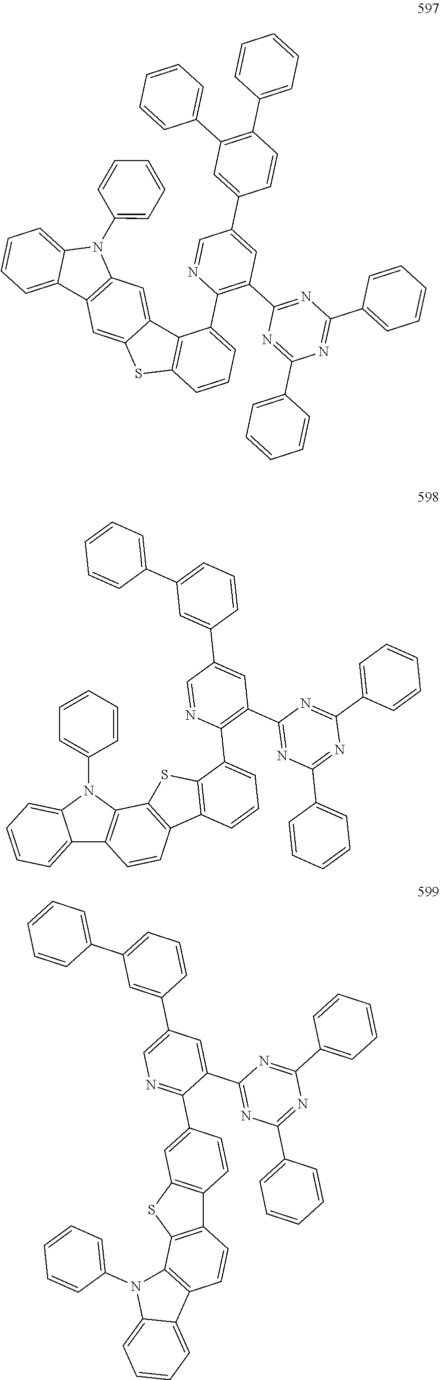

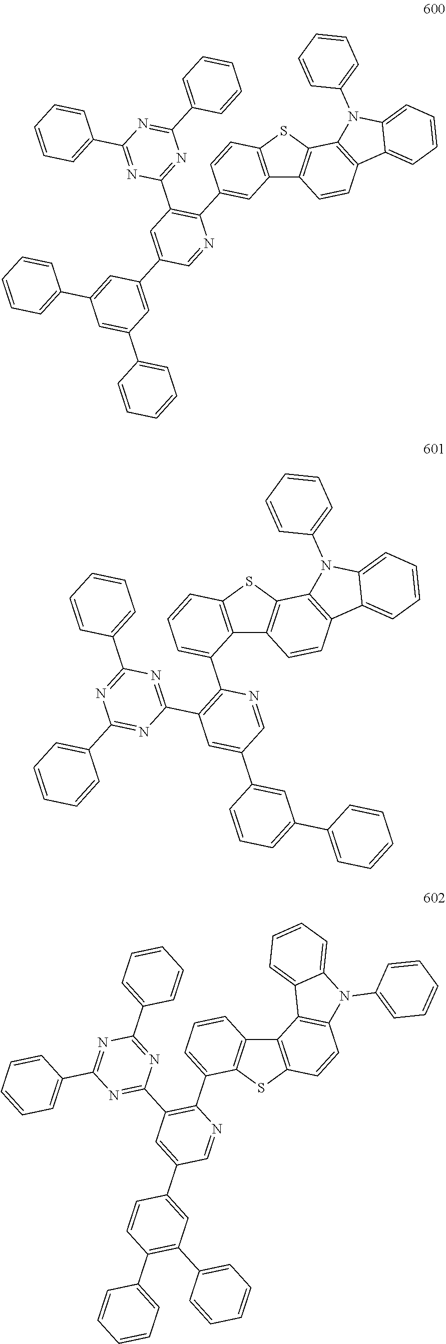 [SMILES: c1ccc(-c2cc(-c3ccccc3)cc(-c3cnc(-c4ccc5sc6c(ccc7c8ccccc8n(-c8ccccc8)c76)c5c4)c(-c4nc(-c5ccccc5)nc(-c5ccccc5)n4)c3)c2)cc1 ; c1ccc(-c2cccc(-c3cnc(-c4cccc5sc6c(ccc7c8ccccc8n(-c8ccccc8)c76)c45)c(-c4nc(-c5ccccc5)nc(-c5ccccc5)n4)c3)c2)cc1 ; c1ccc(-c2nc(-c3ccccc3)nc(-c3cc(-c4ccc(-c5ccccc5)c(-c5ccccc5)c4)cnc3-c3cccc4c3sc3ccc5c(c6ccccc6n5-c5ccccc5)c34)n2)cc1]

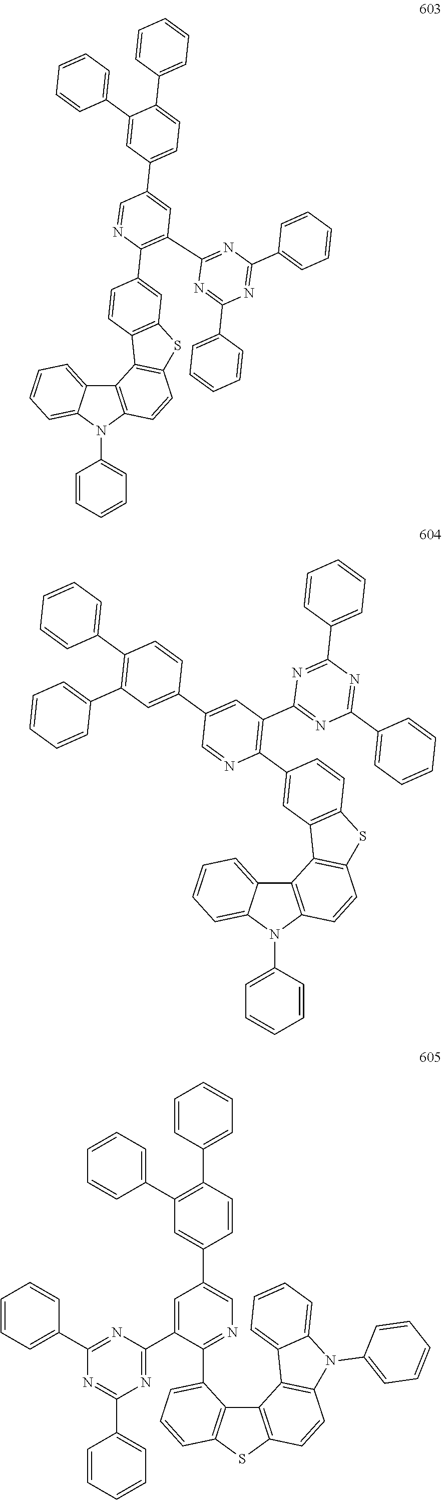 [SMILES: c1ccc(-c2nc(-c3ccccc3)nc(-c3cc(-c4ccc(-c5ccccc5)c(-c5ccccc5)c4)cnc3-c3ccc4c(c3)sc3ccc5c(c6ccccc6n5-c5ccccc5)c34)n2)cc1 ; c1ccc(-c2nc(-c3ccccc3)nc(-c3cc(-c4ccc(-c5ccccc5)c(-c5ccccc5)c4)cnc3-c3ccc4sc5ccc6c(c7ccccc7n6-c6ccccc6)c5c4c3)n2)cc1 ; c1ccc(-c2nc(-c3ccccc3)nc(-c3cc(-c4ccc(-c5ccccc5)c(-c5ccccc5)c4)cnc3-c3cccc4sc5ccc6c(c7ccccc7n6-c6ccccc6)c5c34)n2)cc1]

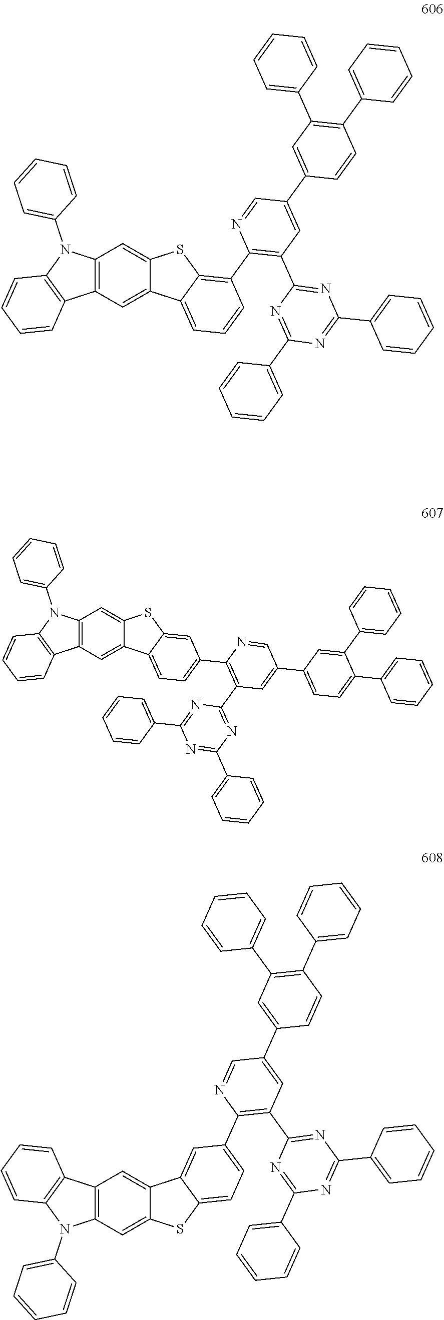 [SMILES: c1ccc(-c2nc(-c3ccccc3)nc(-c3cc(-c4ccc(-c5ccccc5)c(-c5ccccc5)c4)cnc3-c3cccc4c3sc3cc5c(cc34)c3ccccc3n5-c3ccccc3)n2)cc1 ; c1ccc(-c2nc(-c3ccccc3)nc(-c3cc(-c4ccc(-c5ccccc5)c(-c5ccccc5)c4)cnc3-c3ccc4c(c3)sc3cc5c(cc34)c3ccccc3n5-c3ccccc3)n2)cc1 ; c1ccc(-c2nc(-c3ccccc3)nc(-c3cc(-c4ccc(-c5ccccc5)c(-c5ccccc5)c4)cnc3-c3ccc4sc5cc6c(cc5c4c3)c3ccccc3n6-c3ccccc3)n2)cc1]

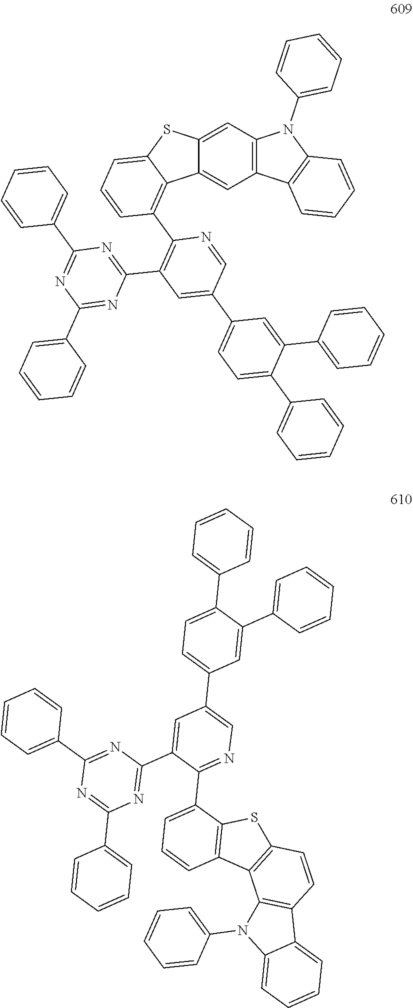 [SMILES: c1ccc(-c2nc(-c3ccccc3)nc(-c3cc(-c4ccc(-c5ccccc5)c(-c5ccccc5)c4)cnc3-c3cccc4sc5cc6c(cc5c34)c3ccccc3n6-c3ccccc3)n2)cc1 ; c1ccc(-c2nc(-c3ccccc3)nc(-c3cc(-c4ccc(-c5ccccc5)c(-c5ccccc5)c4)cnc3-c3cccc4c3sc3ccc5c6ccccc6n(-c6ccccc6)c5c34)n2)cc1]

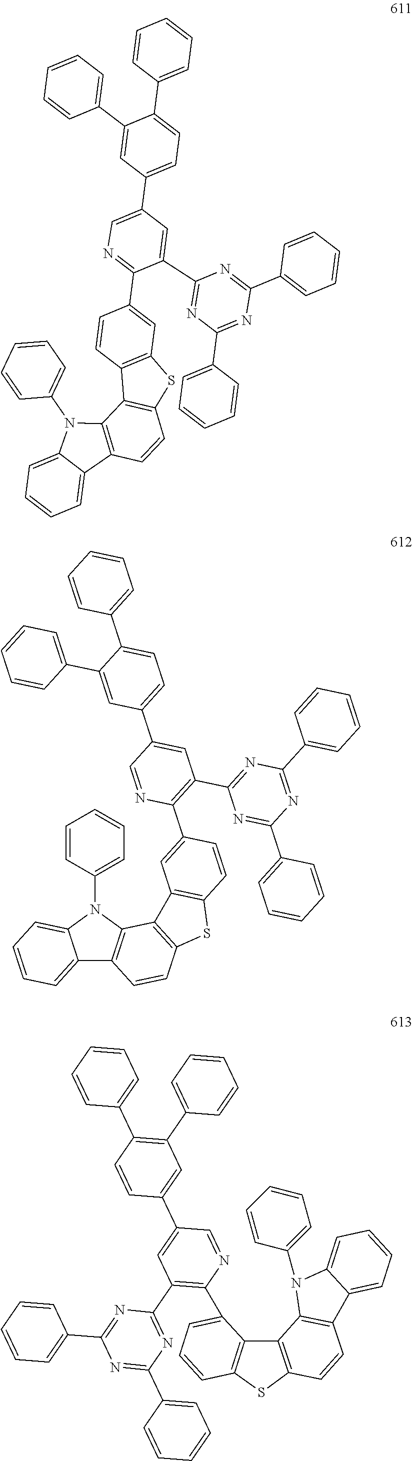 [SMILES: c1ccc(-c2nc(-c3ccccc3)nc(-c3cc(-c4ccc(-c5ccccc5)c(-c5ccccc5)c4)cnc3-c3ccc4c(c3)sc3ccc5c6ccccc6n(-c6ccccc6)c5c34)n2)cc1 ; c1ccc(-c2nc(-c3ccccc3)nc(-c3cc(-c4ccc(-c5ccccc5)c(-c5ccccc5)c4)cnc3-c3ccc4sc5ccc6c7ccccc7n(-c7ccccc7)c6c5c4c3)n2)cc1 ; c1ccc(-c2nc(-c3ccccc3)nc(-c3cc(-c4ccc(-c5ccccc5)c(-c5ccccc5)c4)cnc3-c3cccc4sc5ccc6c7ccccc7n(-c7ccccc7)c6c5c34)n2)cc1]

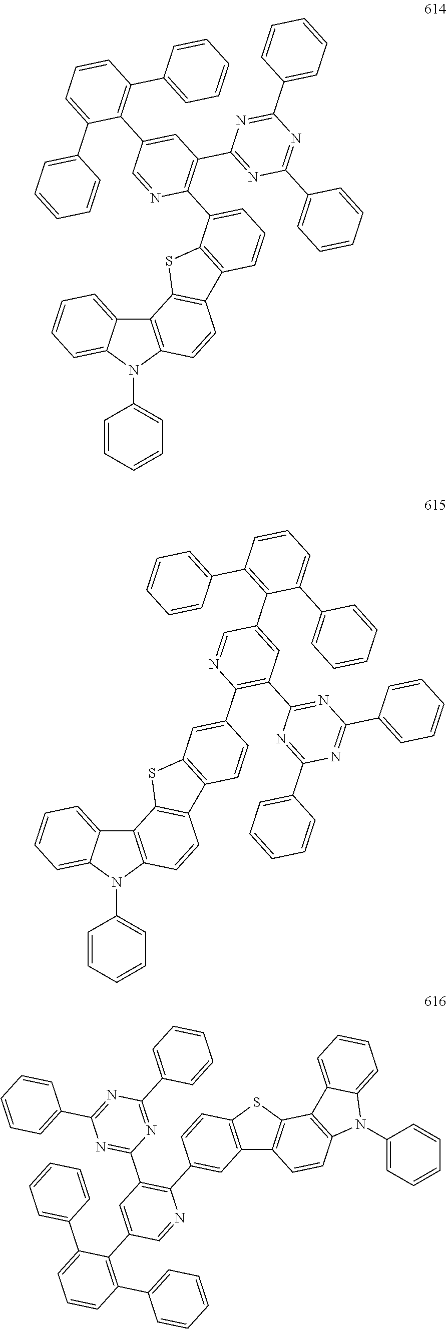 [SMILES: c1ccc(-c2nc(-c3ccccc3)nc(-c3cc(-c4c(-c5ccccc5)cccc4-c4ccccc4)cnc3-c3cccc4c3sc3c4ccc4c3c3ccccc3n4-c3ccccc3)n2)cc1 ; c1ccc(-c2nc(-c3ccccc3)nc(-c3cc(-c4c(-c5ccccc5)cccc4-c4ccccc4)cnc3-c3ccc4c(c3)sc3c4ccc4c3c3ccccc3n4-c3ccccc3)n2)cc1 ; c1ccc(-c2nc(-c3ccccc3)nc(-c3cc(-c4c(-c5ccccc5)cccc4-c4ccccc4)cnc3-c3ccc4sc5c(ccc6c5c5ccccc5n6-c5ccccc5)c4c3)n2)cc1]

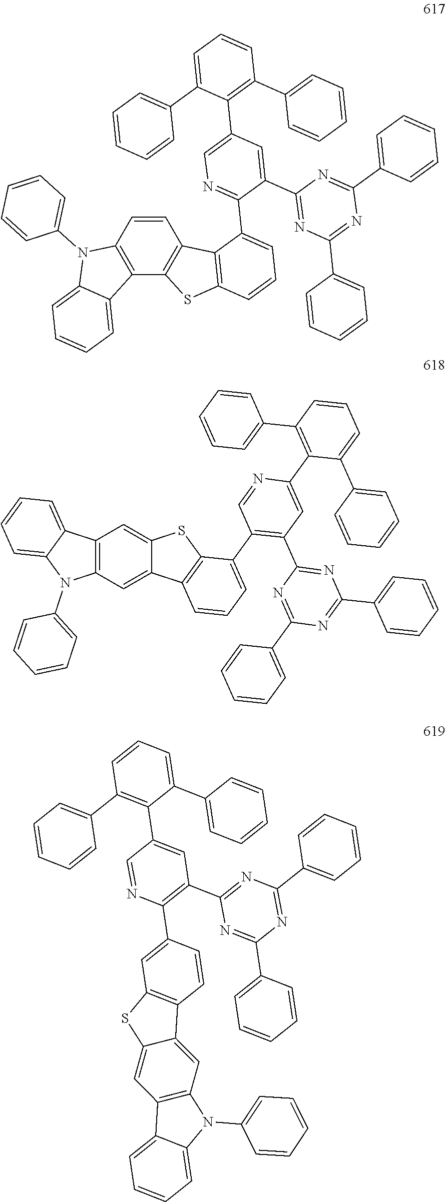 [SMILES: c1ccc(-c2nc(-c3ccccc3)nc(-c3cc(-c4c(-c5ccccc5)cccc4-c4ccccc4)cnc3-c3cccc4sc5c(ccc6c5c5ccccc5n6-c5ccccc5)c34)n2)cc1 ; c1ccc(-c2nc(-c3ccccc3)nc(-c3cc(-c4c(-c5ccccc5)cccc4-c4ccccc4)ncc3-c3cccc4c3sc3cc5c6ccccc6n(-c6ccccc6)c5cc34)n2)cc1 ; c1ccc(-c2nc(-c3ccccc3)nc(-c3cc(-c4c(-c5ccccc5)cccc4-c4ccccc4)cnc3-c3ccc4c(c3)sc3cc5c6ccccc6n(-c6ccccc6)c5cc34)n2)cc1]

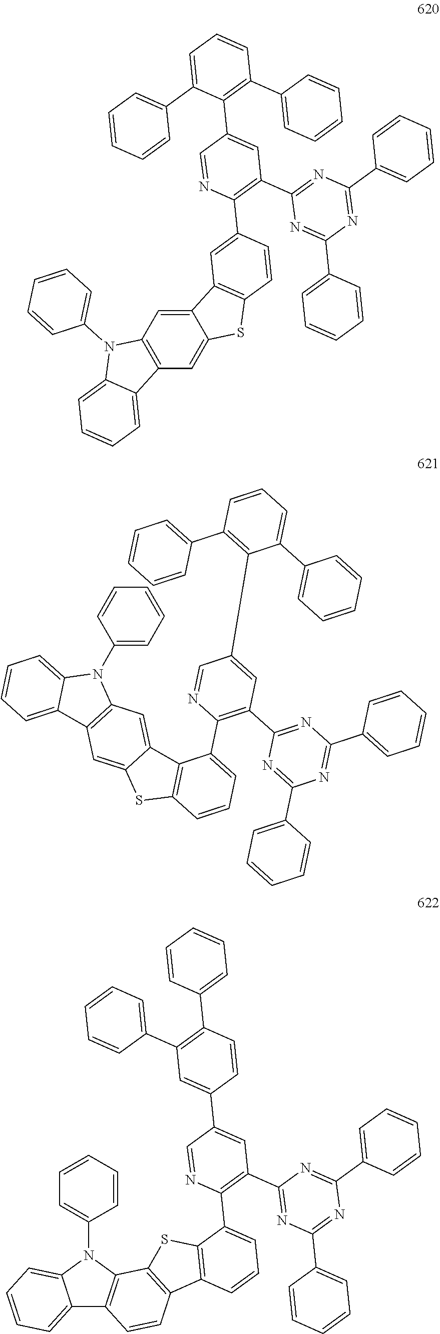 [SMILES: c1ccc(-c2nc(-c3ccccc3)nc(-c3cc(-c4c(-c5ccccc5)cccc4-c4ccccc4)cnc3-c3ccc4sc5cc6c7ccccc7n(-c7ccccc7)c6cc5c4c3)n2)cc1 ; c1ccc(-c2nc(-c3ccccc3)nc(-c3cc(-c4c(-c5ccccc5)cccc4-c4ccccc4)cnc3-c3cccc4sc5cc6c7ccccc7n(-c7ccccc7)c6cc5c34)n2)cc1 ; c1ccc(-c2nc(-c3ccccc3)nc(-c3cc(-c4ccc(-c5ccccc5)c(-c5ccccc5)c4)cnc3-c3cccc4c3sc3c4ccc4c5ccccc5n(-c5ccccc5)c43)n2)cc1]

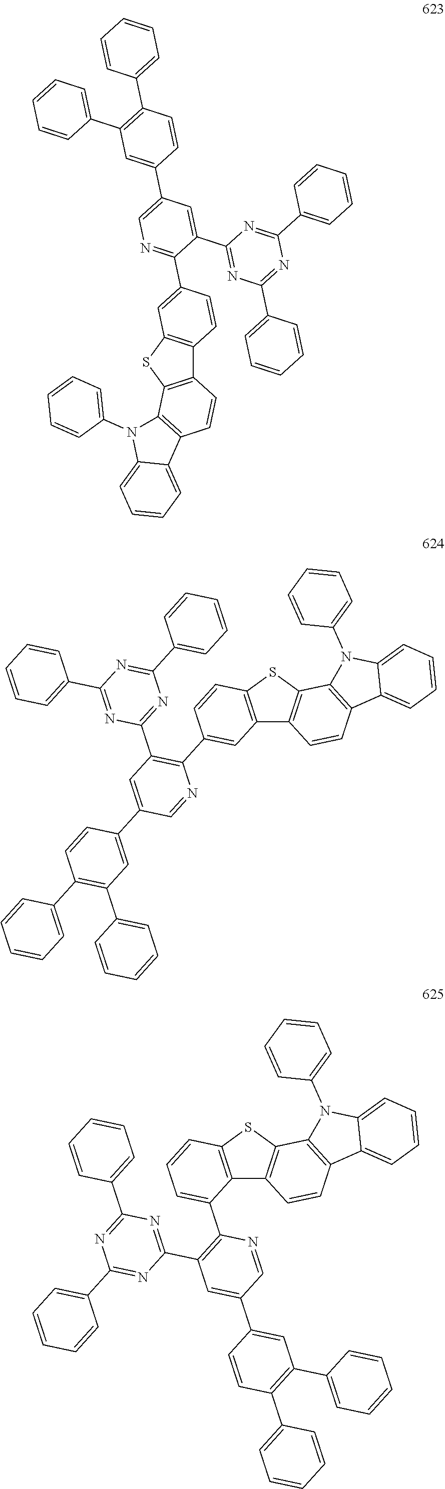 [SMILES: c1ccc(-c2nc(-c3ccccc3)nc(-c3cc(-c4ccc(-c5ccccc5)c(-c5ccccc5)c4)cnc3-c3ccc4c(c3)sc3c4ccc4c5ccccc5n(-c5ccccc5)c43)n2)cc1 ; c1ccc(-c2nc(-c3ccccc3)nc(-c3cc(-c4ccc(-c5ccccc5)c(-c5ccccc5)c4)cnc3-c3ccc4sc5c(ccc6c7ccccc7n(-c7ccccc7)c65)c4c3)n2)cc1 ; c1ccc(-c2nc(-c3ccccc3)nc(-c3cc(-c4ccc(-c5ccccc5)c(-c5ccccc5)c4)cnc3-c3cccc4sc5c(ccc6c7ccccc7n(-c7ccccc7)c65)c34)n2)cc1]

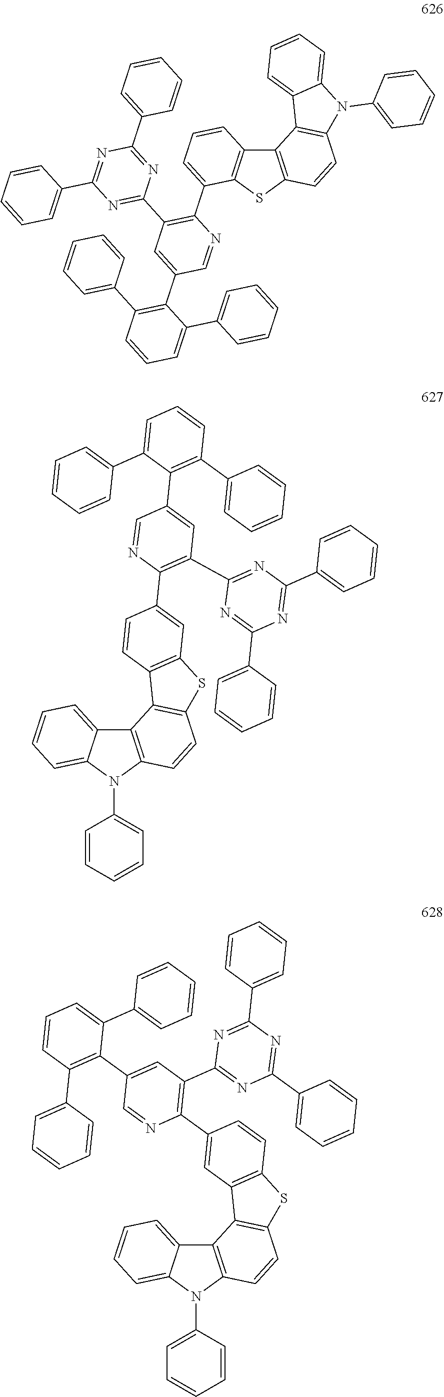 [SMILES: c1ccc(-c2nc(-c3ccccc3)nc(-c3cc(-c4c(-c5ccccc5)cccc4-c4ccccc4)cnc3-c3cccc4c3sc3ccc5c(c6ccccc6n5-c5ccccc5)c34)n2)cc1 ; c1ccc(-c2nc(-c3ccccc3)nc(-c3cc(-c4c(-c5ccccc5)cccc4-c4ccccc4)cnc3-c3ccc4c(c3)sc3ccc5c(c6ccccc6n5-c5ccccc5)c34)n2)cc1 ; c1ccc(-c2nc(-c3ccccc3)nc(-c3cc(-c4c(-c5ccccc5)cccc4-c4ccccc4)cnc3-c3ccc4sc5ccc6c(c7ccccc7n6-c6ccccc6)c5c4c3)n2)cc1]

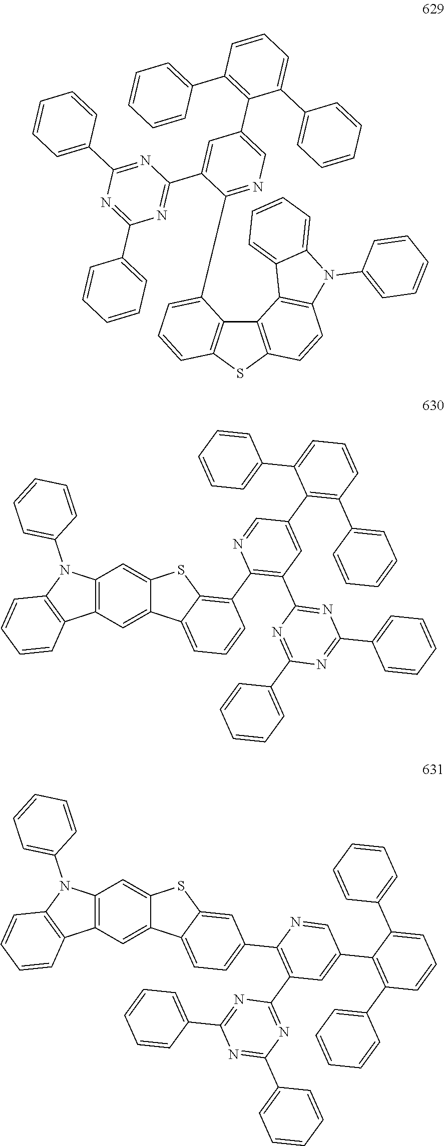 [SMILES: c1ccc(-c2nc(-c3ccccc3)nc(-c3cc(-c4c(-c5ccccc5)cccc4-c4ccccc4)cnc3-c3cccc4sc5ccc6c(c7ccccc7n6-c6ccccc6)c5c34)n2)cc1 ; c1ccc(-c2nc(-c3ccccc3)nc(-c3cc(-c4c(-c5ccccc5)cccc4-c4ccccc4)cnc3-c3cccc4c3sc3cc5c(cc34)c3ccccc3n5-c3ccccc3)n2)cc1 ; c1ccc(-c2nc(-c3ccccc3)nc(-c3cc(-c4c(-c5ccccc5)cccc4-c4ccccc4)cnc3-c3ccc4c(c3)sc3cc5c(cc34)c3ccccc3n5-c3ccccc3)n2)cc1]

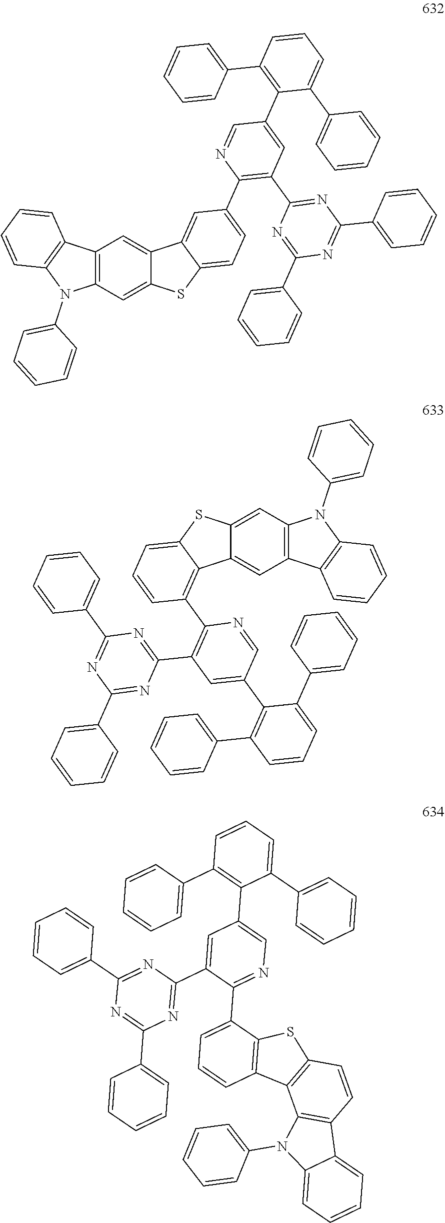 [SMILES: c1ccc(-c2nc(-c3ccccc3)nc(-c3cc(-c4c(-c5ccccc5)cccc4-c4ccccc4)cnc3-c3ccc4sc5cc6c(cc5c4c3)c3ccccc3n6-c3ccccc3)n2)cc1 ; c1ccc(-c2nc(-c3ccccc3)nc(-c3cc(-c4c(-c5ccccc5)cccc4-c4ccccc4)cnc3-c3cccc4sc5cc6c(cc5c34)c3ccccc3n6-c3ccccc3)n2)cc1 ; c1ccc(-c2nc(-c3ccccc3)nc(-c3cc(-c4c(-c5ccccc5)cccc4-c4ccccc4)cnc3-c3cccc4c3sc3ccc5c6ccccc6n(-c6ccccc6)c5c34)n2)cc1]

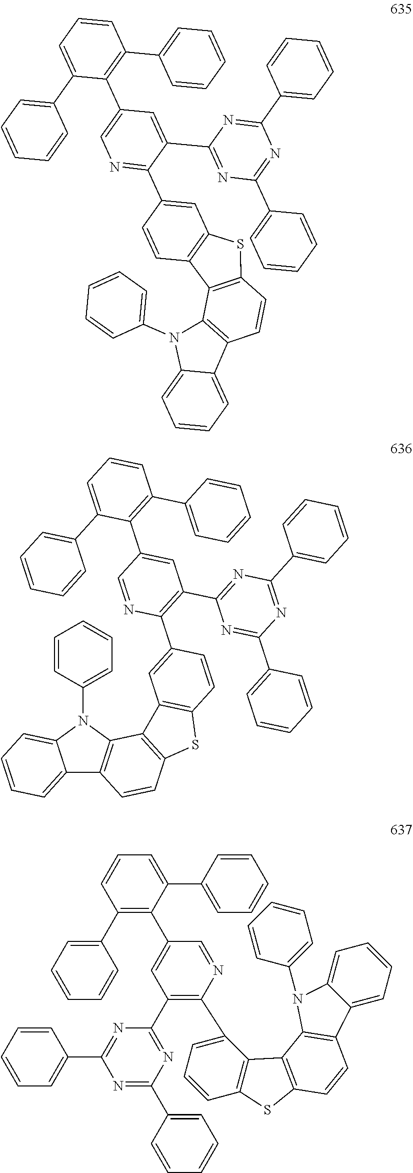 [SMILES: c1ccc(-c2nc(-c3ccccc3)nc(-c3cc(-c4c(-c5ccccc5)cccc4-c4ccccc4)cnc3-c3ccc4c(c3)sc3ccc5c6ccccc6n(-c6ccccc6)c5c34)n2)cc1 ; c1ccc(-c2nc(-c3ccccc3)nc(-c3cc(-c4c(-c5ccccc5)cccc4-c4ccccc4)cnc3-c3ccc4sc5ccc6c7ccccc7n(-c7ccccc7)c6c5c4c3)n2)cc1 ; c1ccc(-c2nc(-c3ccccc3)nc(-c3cc(-c4c(-c5ccccc5)cccc4-c4ccccc4)cnc3-c3cccc4sc5ccc6c7ccccc7n(-c7ccccc7)c6c5c34)n2)cc1]

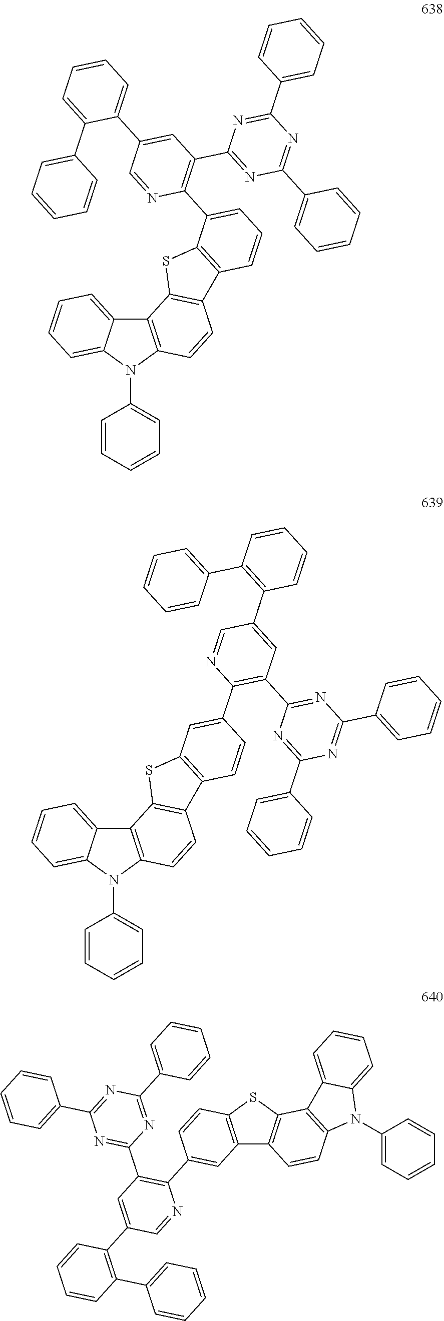 [SMILES: c1ccc(-c2nc(-c3ccccc3)nc(-c3cc(-c4ccccc4-c4ccccc4)cnc3-c3cccc4c3sc3c4ccc4c3c3ccccc3n4-c3ccccc3)n2)cc1 ; c1ccc(-c2nc(-c3ccccc3)nc(-c3cc(-c4ccccc4-c4ccccc4)cnc3-c3ccc4c(c3)sc3c4ccc4c3c3ccccc3n4-c3ccccc3)n2)cc1 ; c1ccc(-c2nc(-c3ccccc3)nc(-c3cc(-c4ccccc4-c4ccccc4)cnc3-c3ccc4sc5c(ccc6c5c5ccccc5n6-c5ccccc5)c4c3)n2)cc1]

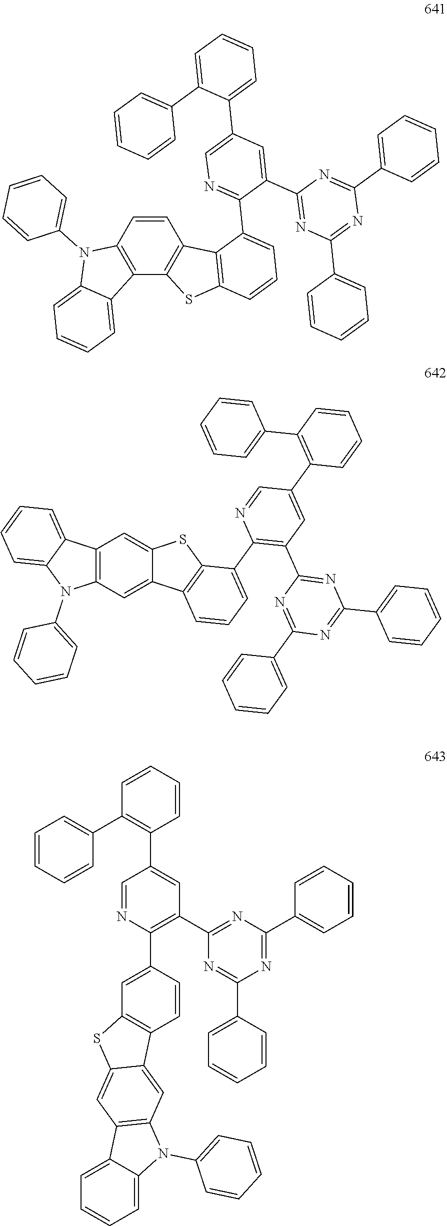 [SMILES: c1ccc(-c2nc(-c3ccccc3)nc(-c3cc(-c4ccccc4-c4ccccc4)cnc3-c3cccc4sc5c(ccc6c5c5ccccc5n6-c5ccccc5)c34)n2)cc1 ; c1ccc(-c2nc(-c3ccccc3)nc(-c3cc(-c4ccccc4-c4ccccc4)cnc3-c3cccc4c3sc3cc5c6ccccc6n(-c6ccccc6)c5cc34)n2)cc1 ; c1ccc(-c2nc(-c3ccccc3)nc(-c3cc(-c4ccccc4-c4ccccc4)cnc3-c3ccc4c(c3)sc3cc5c6ccccc6n(-c6ccccc6)c5cc34)n2)cc1]

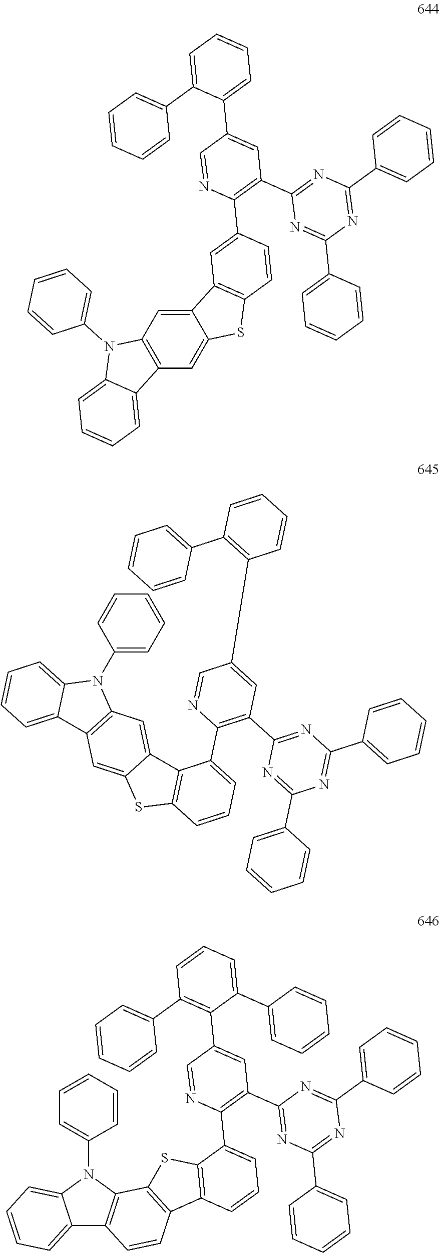 [SMILES: c1ccc(-c2nc(-c3ccccc3)nc(-c3cc(-c4ccccc4-c4ccccc4)cnc3-c3ccc4sc5cc6c7ccccc7n(-c7ccccc7)c6cc5c4c3)n2)cc1 ; c1ccc(-c2nc(-c3ccccc3)nc(-c3cc(-c4ccccc4-c4ccccc4)cnc3-c3cccc4sc5cc6c7ccccc7n(-c7ccccc7)c6cc5c34)n2)cc1 ; c1ccc(-c2nc(-c3ccccc3)nc(-c3cc(-c4c(-c5ccccc5)cccc4-c4ccccc4)cnc3-c3cccc4c3sc3c4ccc4c5ccccc5n(-c5ccccc5)c43)n2)cc1]

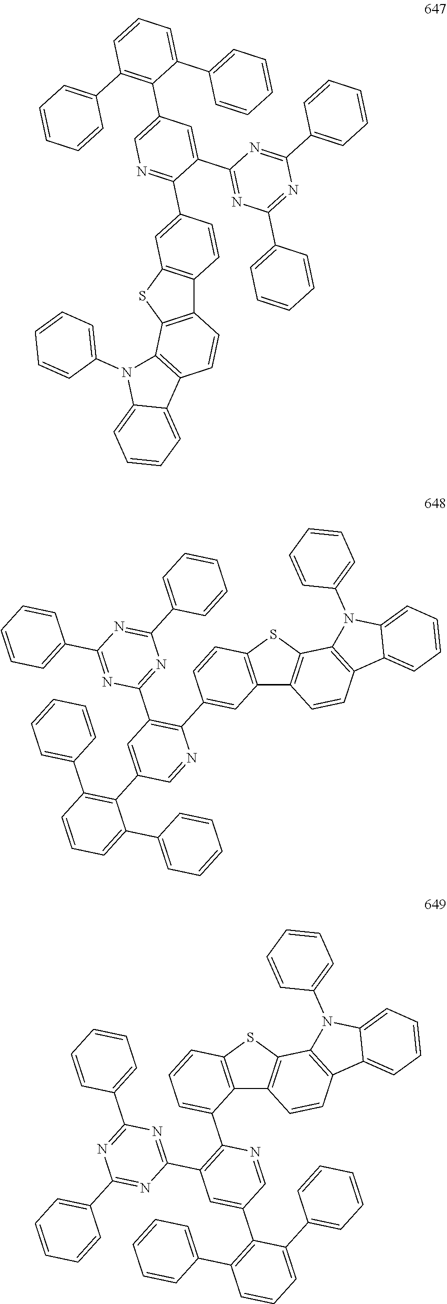 [SMILES: c1ccc(-c2nc(-c3ccccc3)nc(-c3cc(-c4c(-c5ccccc5)cccc4-c4ccccc4)cnc3-c3ccc4c(c3)sc3c4ccc4c5ccccc5n(-c5ccccc5)c43)n2)cc1 ; c1ccc(-c2nc(-c3ccccc3)nc(-c3cc(-c4c(-c5ccccc5)cccc4-c4ccccc4)cnc3-c3ccc4sc5c(ccc6c7ccccc7n(-c7ccccc7)c65)c4c3)n2)cc1 ; c1ccc(-c2nc(-c3ccccc3)nc(-c3cc(-c4c(-c5ccccc5)cccc4-c4ccccc4)cnc3-c3cccc4sc5c(ccc6c7ccccc7n(-c7ccccc7)c65)c34)n2)cc1]

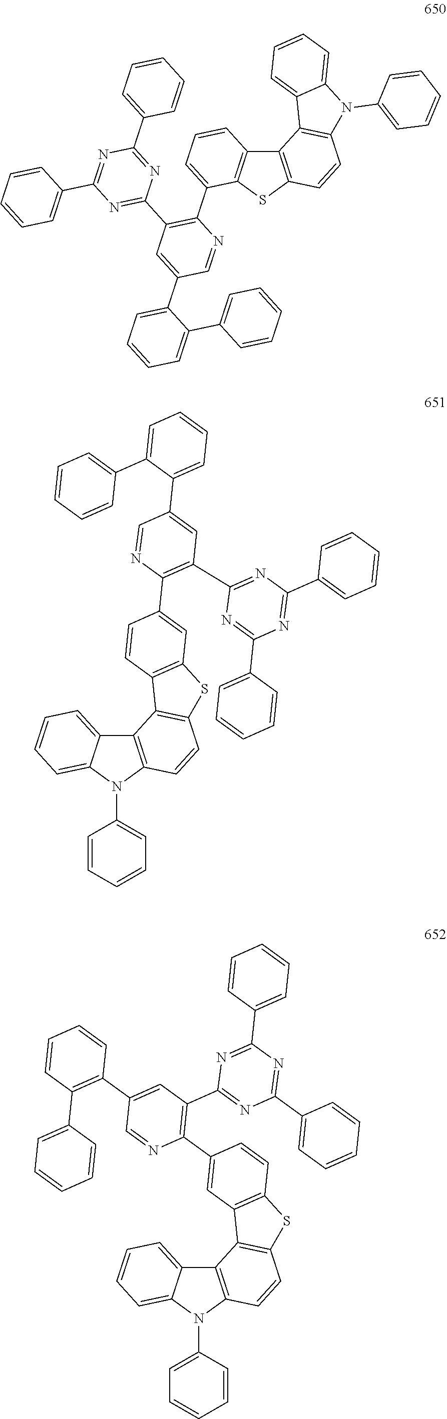 [SMILES: c1ccc(-c2nc(-c3ccccc3)nc(-c3cc(-c4ccccc4-c4ccccc4)cnc3-c3cccc4c3sc3ccc5c(c6ccccc6n5-c5ccccc5)c34)n2)cc1 ; c1ccc(-c2nc(-c3ccccc3)nc(-c3cc(-c4ccccc4-c4ccccc4)cnc3-c3ccc4c(c3)sc3ccc5c(c6ccccc6n5-c5ccccc5)c34)n2)cc1 ; c1ccc(-c2nc(-c3ccccc3)nc(-c3cc(-c4ccccc4-c4ccccc4)cnc3-c3ccc4sc5ccc6c(c7ccccc7n6-c6ccccc6)c5c4c3)n2)cc1]

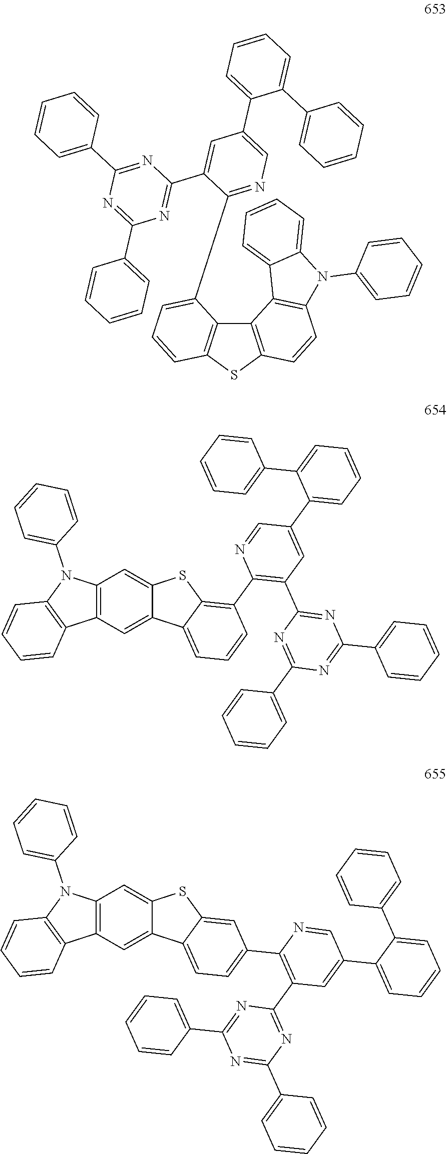

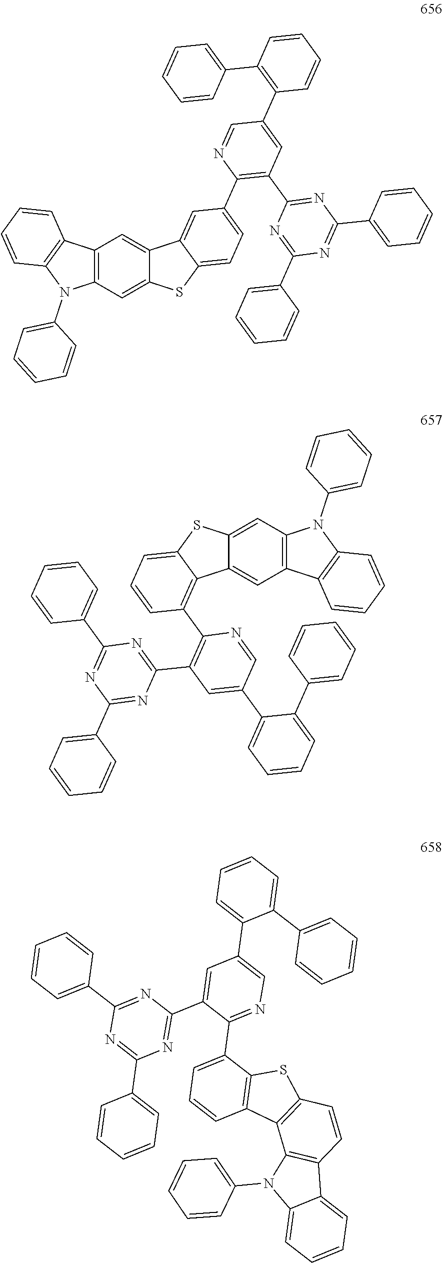 [SMILES: c1ccc(-c2nc(-c3ccccc3)nc(-c3cc(-c4ccccc4-c4ccccc4)cnc3-c3ccc4sc5cc6c(cc5c4c3)c3ccccc3n6-c3ccccc3)n2)cc1 ; c1ccc(-c2nc(-c3ccccc3)nc(-c3cc(-c4ccccc4-c4ccccc4)cnc3-c3cccc4sc5cc6c(cc5c34)c3ccccc3n6-c3ccccc3)n2)cc1 ; c1ccc(-c2nc(-c3ccccc3)nc(-c3cc(-c4ccccc4-c4ccccc4)cnc3-c3cccc4c3sc3ccc5c6ccccc6n(-c6ccccc6)c5c34)n2)cc1]

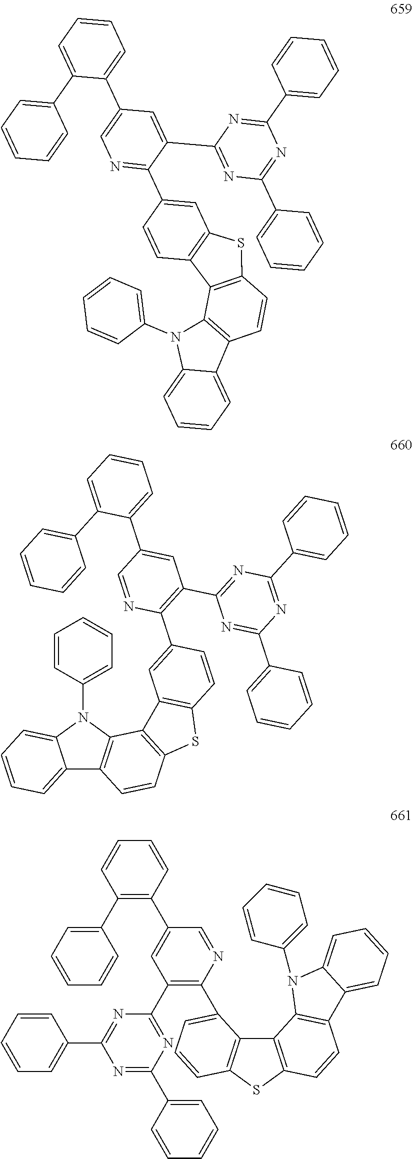 [SMILES: c1ccc(-c2nc(-c3ccccc3)nc(-c3cc(-c4ccccc4-c4ccccc4)cnc3-c3ccc4c(c3)sc3ccc5c6ccccc6n(-c6ccccc6)c5c34)n2)cc1 ; c1ccc(-c2nc(-c3ccccc3)nc(-c3cc(-c4ccccc4-c4ccccc4)cnc3-c3ccc4sc5ccc6c7ccccc7n(-c7ccccc7)c6c5c4c3)n2)cc1 ; c1ccc(-c2nc(-c3ccccc3)nc(-c3cc(-c4ccccc4-c4ccccc4)cnc3-c3cccc4sc5ccc6c7ccccc7n(-c7ccccc7)c6c5c34)n2)cc1]

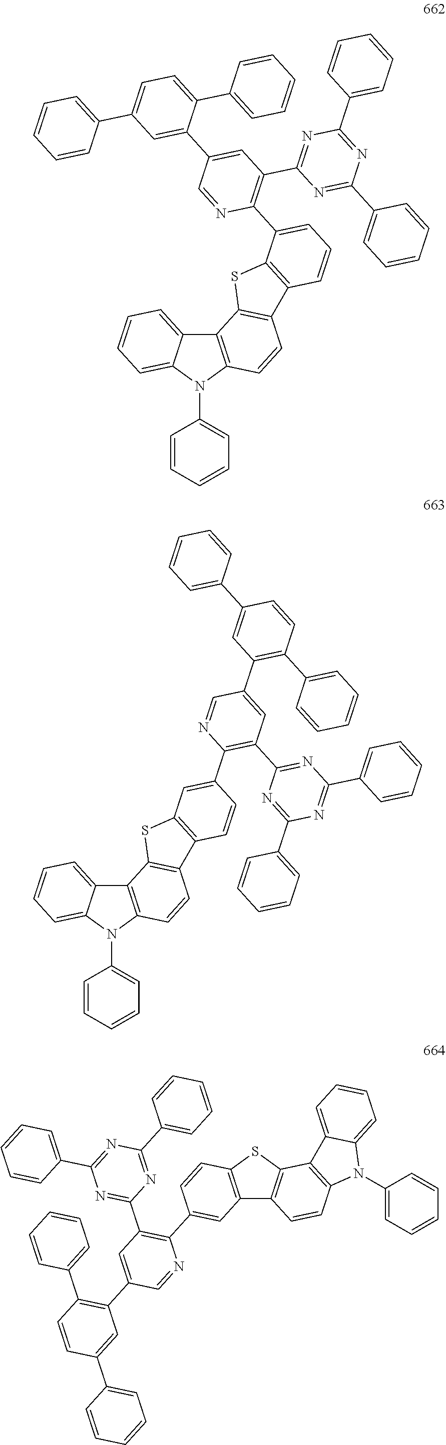 [SMILES: c1ccc(-c2ccc(-c3ccccc3)c(-c3cnc(-c4cccc5c4sc4c5ccc5c4c4ccccc4n5-c4ccccc4)c(-c4nc(-c5ccccc5)nc(-c5ccccc5)n4)c3)c2)cc1 ; c1ccc(-c2ccc(-c3ccccc3)c(-c3cnc(-c4ccc5c(c4)sc4c5ccc5c4c4ccccc4n5-c4ccccc4)c(-c4nc(-c5ccccc5)nc(-c5ccccc5)n4)c3)c2)cc1 ; c1ccc(-c2ccc(-c3ccccc3)c(-c3cnc(-c4ccc5sc6c(ccc7c6c6ccccc6n7-c6ccccc6)c5c4)c(-c4nc(-c5ccccc5)nc(-c5ccccc5)n4)c3)c2)cc1]

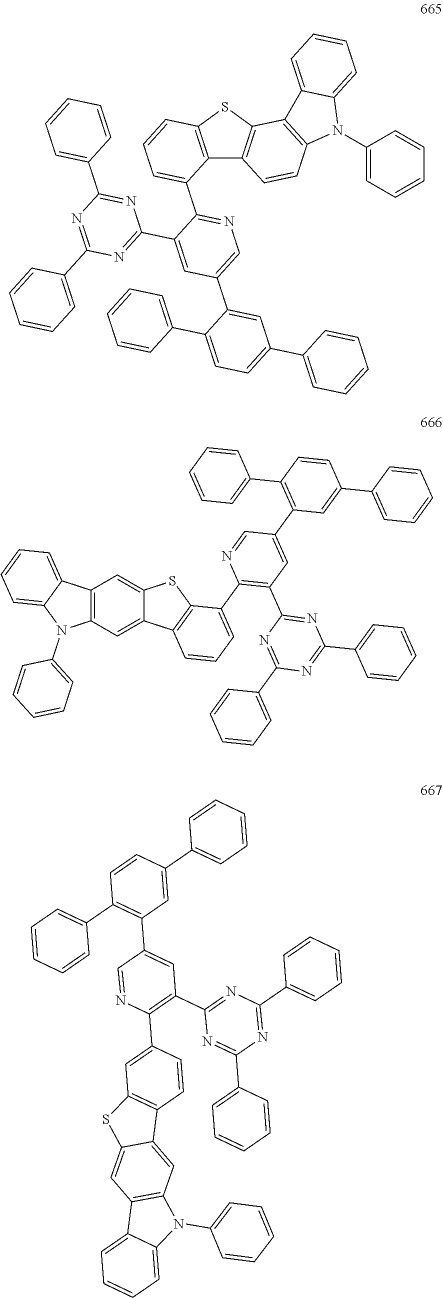 [SMILES: c1ccc(-c2ccc(-c3ccccc3)c(-c3cnc(-c4cccc5sc6c(ccc7c6c6ccccc6n7-c6ccccc6)c45)c(-c4nc(-c5ccccc5)nc(-c5ccccc5)n4)c3)c2)cc1 ; c1ccc(-c2ccc(-c3ccccc3)c(-c3cnc(-c4cccc5c4sc4cc6c7ccccc7n(-c7ccccc7)c6cc45)c(-c4nc(-c5ccccc5)nc(-c5ccccc5)n4)c3)c2)cc1 ; c1ccc(-c2ccc(-c3ccccc3)c(-c3cnc(-c4ccc5c(c4)sc4cc6c7ccccc7n(-c7ccccc7)c6cc45)c(-c4nc(-c5ccccc5)nc(-c5ccccc5)n4)c3)c2)cc1]

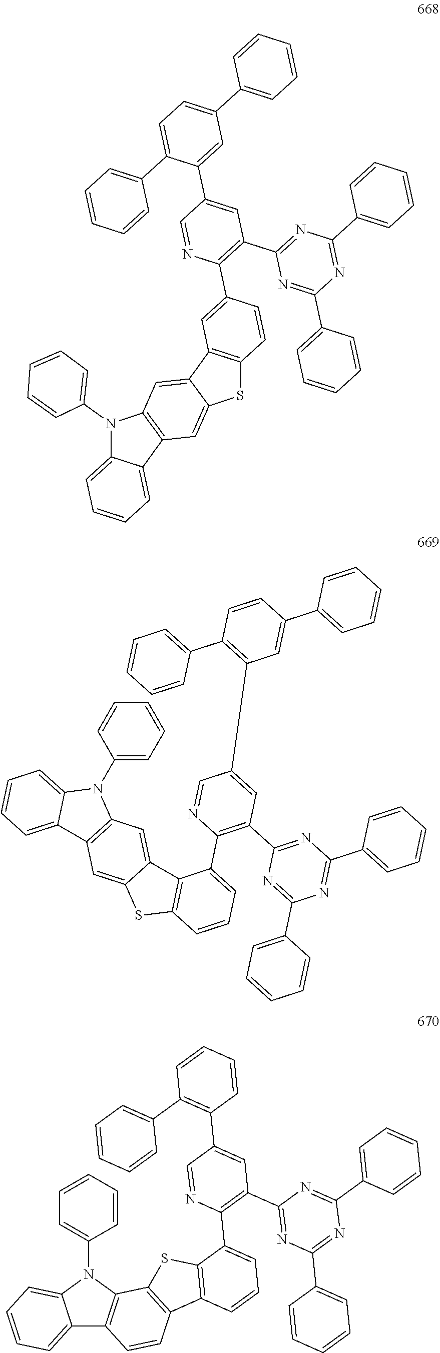 [SMILES: c1ccc(-c2ccc(-c3ccccc3)c(-c3cnc(-c4ccc5sc6cc7c8ccccc8n(-c8ccccc8)c7cc6c5c4)c(-c4nc(-c5ccccc5)nc(-c5ccccc5)n4)c3)c2)cc1 ; c1ccc(-c2ccc(-c3ccccc3)c(-c3cnc(-c4cccc5sc6cc7c8ccccc8n(-c8ccccc8)c7cc6c45)c(-c4nc(-c5ccccc5)nc(-c5ccccc5)n4)c3)c2)cc1 ; c1ccc(-c2nc(-c3ccccc3)nc(-c3cc(-c4ccccc4-c4ccccc4)cnc3-c3cccc4c3sc3c4ccc4c5ccccc5n(-c5ccccc5)c43)n2)cc1]

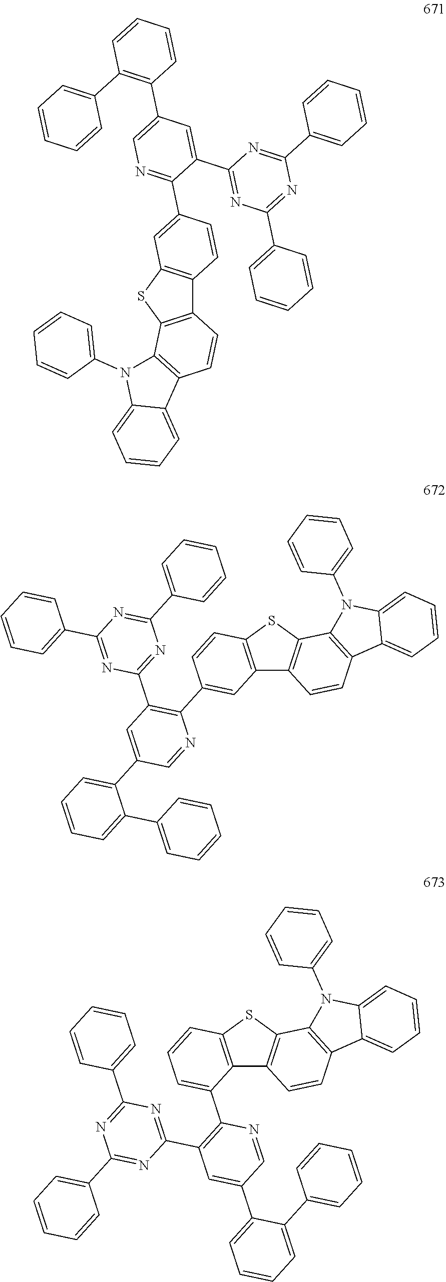 [SMILES: c1ccc(-c2nc(-c3ccccc3)nc(-c3cc(-c4ccccc4-c4ccccc4)cnc3-c3ccc4c(c3)sc3c4ccc4c5ccccc5n(-c5ccccc5)c43)n2)cc1 ; c1ccc(-c2nc(-c3ccccc3)nc(-c3cc(-c4ccccc4-c4ccccc4)cnc3-c3ccc4sc5c(ccc6c7ccccc7n(-c7ccccc7)c65)c4c3)n2)cc1 ; c1ccc(-c2nc(-c3ccccc3)nc(-c3cc(-c4ccccc4-c4ccccc4)cnc3-c3cccc4sc5c(ccc6c7ccccc7n(-c7ccccc7)c65)c34)n2)cc1]

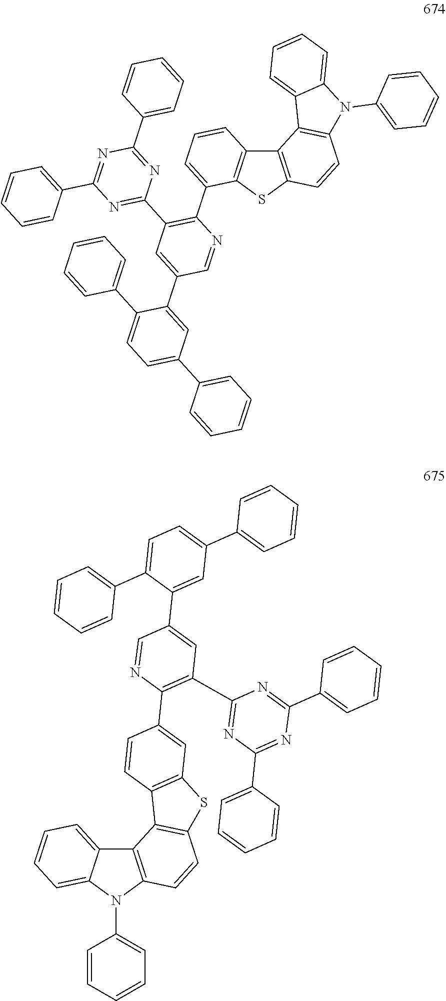 [SMILES: c1ccc(-c2ccc(-c3ccccc3)c(-c3cnc(-c4cccc5c4sc4ccc6c(c7ccccc7n6-c6ccccc6)c45)c(-c4nc(-c5ccccc5)nc(-c5ccccc5)n4)c3)c2)cc1 ; c1ccc(-c2ccc(-c3ccccc3)c(-c3cnc(-c4ccc5c(c4)sc4ccc6c(c7ccccc7n6-c6ccccc6)c45)c(-c4nc(-c5ccccc5)nc(-c5ccccc5)n4)c3)c2)cc1]

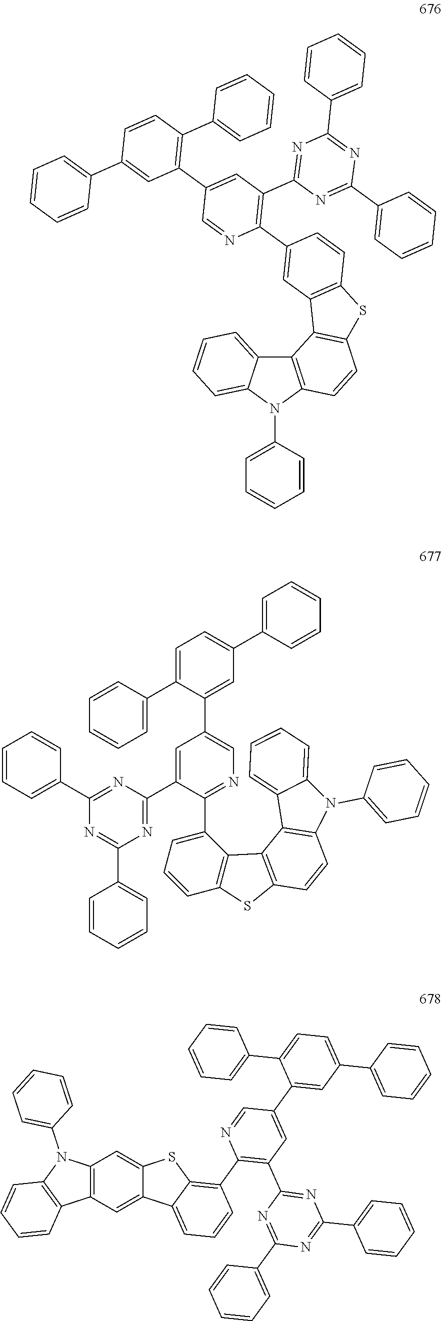 [SMILES: c1ccc(-c2ccc(-c3ccccc3)c(-c3cnc(-c4ccc5sc6ccc7c(c8ccccc8n7-c7ccccc7)c6c5c4)c(-c4nc(-c5ccccc5)nc(-c5ccccc5)n4)c3)c2)cc1 ; c1ccc(-c2ccc(-c3ccccc3)c(-c3cnc(-c4cccc5sc6ccc7c(c8ccccc8n7-c7ccccc7)c6c45)c(-c4nc(-c5ccccc5)nc(-c5ccccc5)n4)c3)c2)cc1 ; c1ccc(-c2ccc(-c3ccccc3)c(-c3cnc(-c4cccc5c4sc4cc6c(cc45)c4ccccc4n6-c4ccccc4)c(-c4nc(-c5ccccc5)nc(-c5ccccc5)n4)c3)c2)cc1]

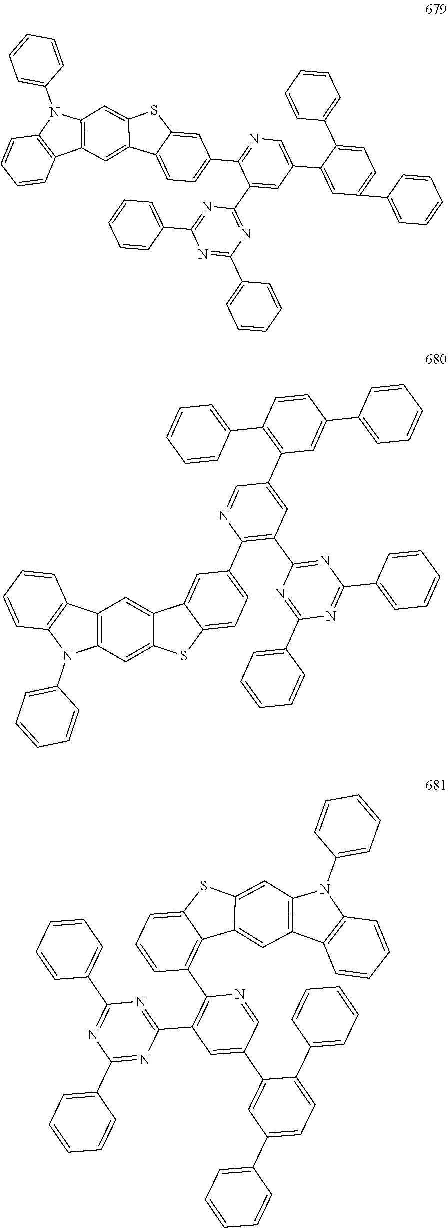 [SMILES: c1ccc(-c2ccc(-c3ccccc3)c(-c3cnc(-c4ccc5c(c4)sc4cc6c(cc45)c4ccccc4n6-c4ccccc4)c(-c4nc(-c5ccccc5)nc(-c5ccccc5)n4)c3)c2)cc1 ; c1ccc(-c2ccc(-c3ccccc3)c(-c3cnc(-c4ccc5sc6cc7c(cc6c5c4)c4ccccc4n7-c4ccccc4)c(-c4nc(-c5ccccc5)nc(-c5ccccc5)n4)c3)c2)cc1 ; c1ccc(-c2ccc(-c3ccccc3)c(-c3cnc(-c4cccc5sc6cc7c(cc6c45)c4ccccc4n7-c4ccccc4)c(-c4nc(-c5ccccc5)nc(-c5ccccc5)n4)c3)c2)cc1]

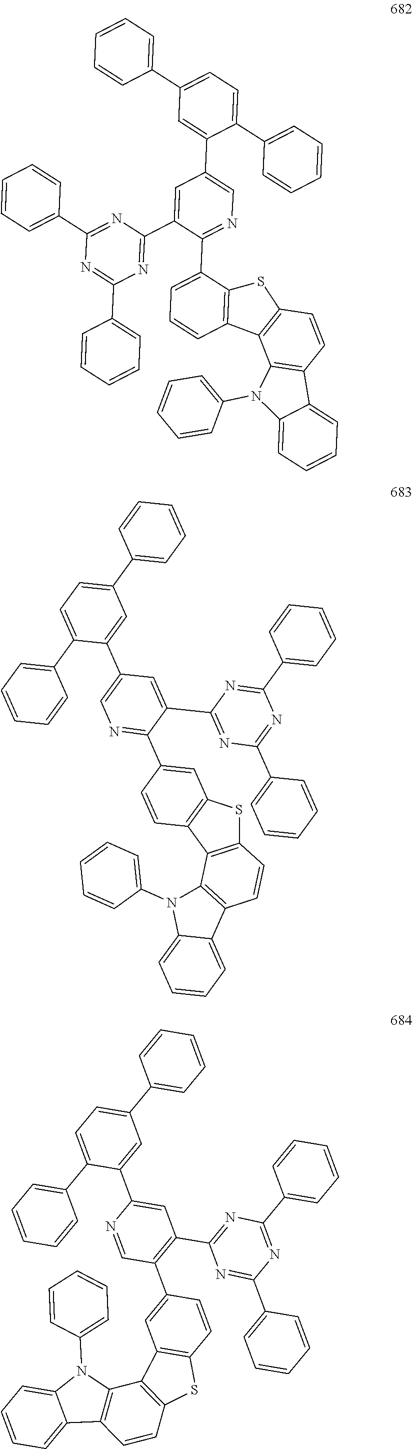

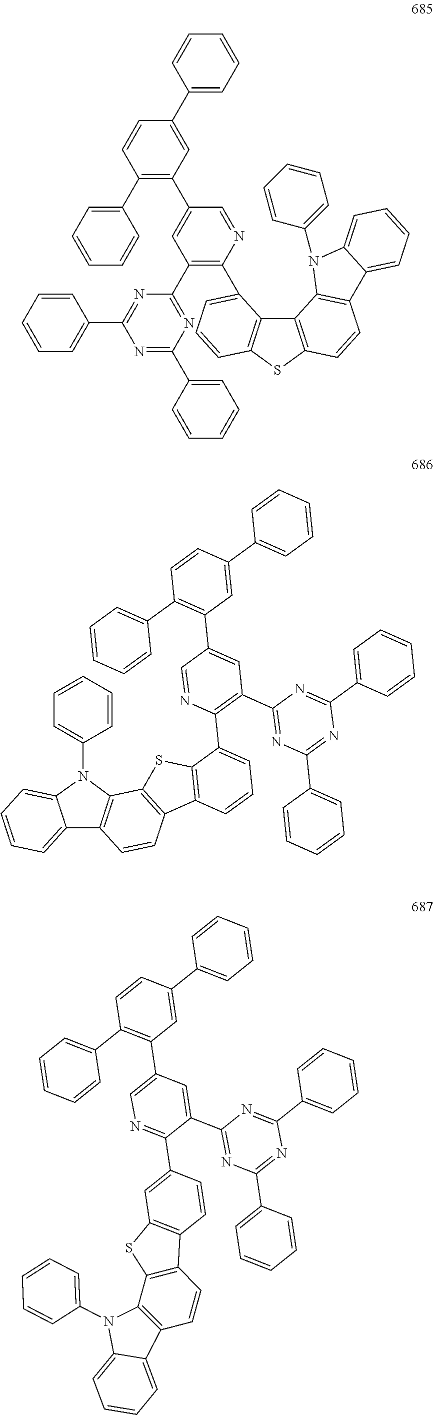 [SMILES: c1ccc(-c2ccc(-c3ccccc3)c(-c3cnc(-c4cccc5sc6ccc7c8ccccc8n(-c8ccccc8)c7c6c45)c(-c4nc(-c5ccccc5)nc(-c5ccccc5)n4)c3)c2)cc1 ; c1ccc(-c2ccc(-c3ccccc3)c(-c3cnc(-c4cccc5c4sc4c5ccc5c6ccccc6n(-c6ccccc6)c54)c(-c4nc(-c5ccccc5)nc(-c5ccccc5)n4)c3)c2)cc1 ; c1ccc(-c2ccc(-c3ccccc3)c(-c3cnc(-c4ccc5c(c4)sc4c5ccc5c6ccccc6n(-c6ccccc6)c54)c(-c4nc(-c5ccccc5)nc(-c5ccccc5)n4)c3)c2)cc1]

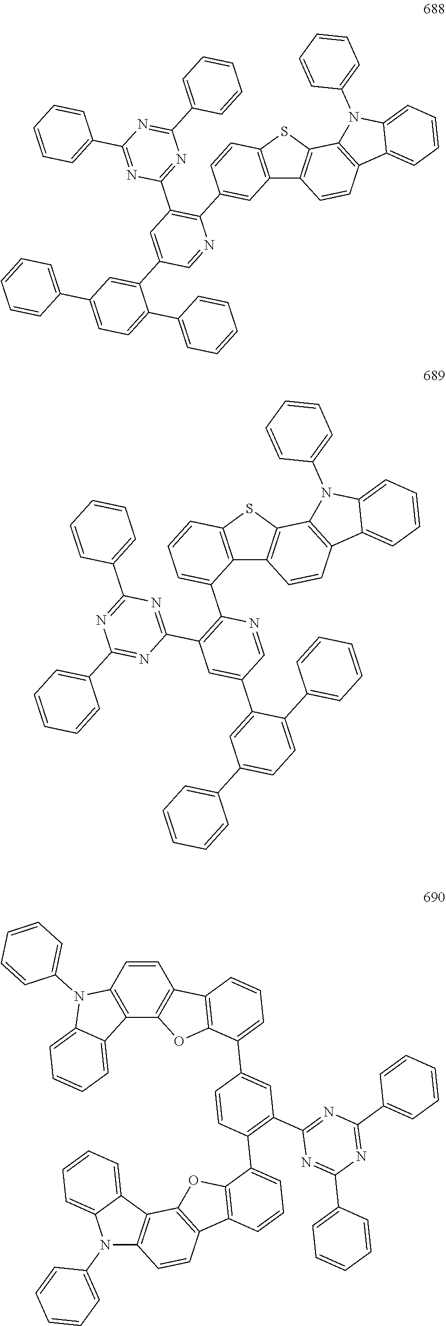 [SMILES: c1ccc(-c2ccc(-c3ccccc3)c(-c3cnc(-c4ccc5sc6c(ccc7c8ccccc8n(-c8ccccc8)c76)c5c4)c(-c4nc(-c5ccccc5)nc(-c5ccccc5)n4)c3)c2)cc1 ; c1ccc(-c2ccc(-c3ccccc3)c(-c3cnc(-c4cccc5sc6c(ccc7c8ccccc8n(-c8ccccc8)c76)c45)c(-c4nc(-c5ccccc5)nc(-c5ccccc5)n4)c3)c2)cc1 ; c1ccc(-c2nc(-c3ccccc3)nc(-c3cc(-c4cccc5c4oc4c5ccc5c4c4ccccc4n5-c4ccccc4)ccc3-c3cccc4c3oc3c4ccc4c3c3ccccc3n4-c3ccccc3)n2)cc1]

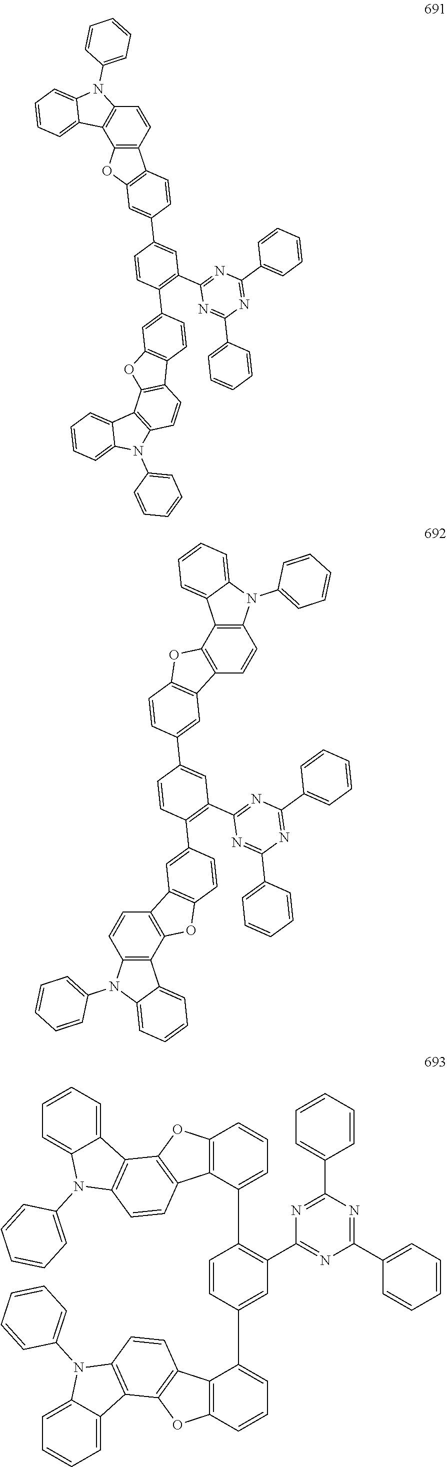 [SMILES: c1ccc(-c2nc(-c3ccccc3)nc(-c3cc(-c4ccc5c(c4)oc4c5ccc5c4c4ccccc4n5-c4ccccc4)ccc3-c3ccc4c(c3)oc3c4ccc4c3c3ccccc3n4-c3ccccc3)n2)cc1 ; c1ccc(-c2nc(-c3ccccc3)nc(-c3cc(-c4ccc5oc6c(ccc7c6c6ccccc6n7-c6ccccc6)c5c4)ccc3-c3ccc4oc5c(ccc6c5c5ccccc5n6-c5ccccc5)c4c3)n2)cc1 ; c1ccc(-c2nc(-c3ccccc3)nc(-c3cc(-c4cccc5oc6c(ccc7c6c6ccccc6n7-c6ccccc6)c45)ccc3-c3cccc4oc5c(ccc6c5c5ccccc5n6-c5ccccc5)c34)n2)cc1]

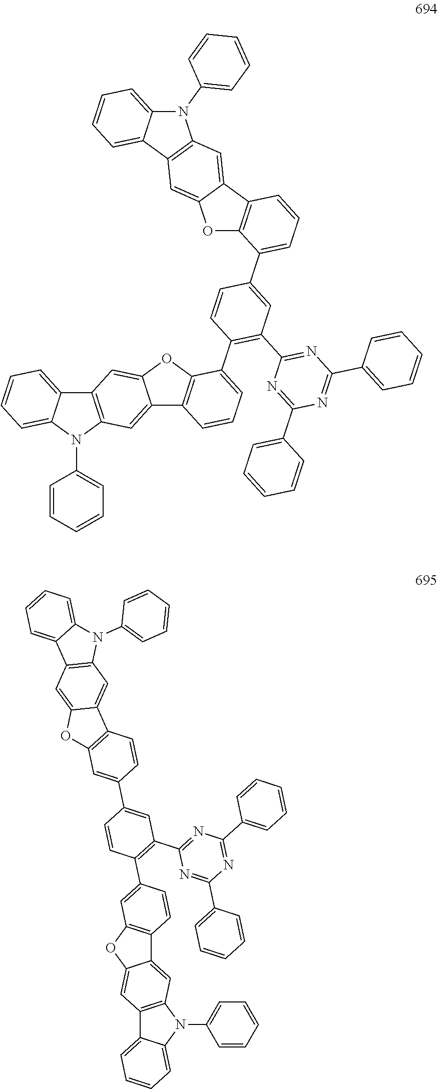 [SMILES: c1ccc(-c2nc(-c3ccccc3)nc(-c3cc(-c4cccc5c4oc4cc6c7ccccc7n(-c7ccccc7)c6cc45)ccc3-c3cccc4c3oc3cc5c6ccccc6n(-c6ccccc6)c5cc34)n2)cc1 ; c1ccc(-c2nc(-c3ccccc3)nc(-c3cc(-c4ccc5c(c4)oc4cc6c7ccccc7n(-c7ccccc7)c6cc45)ccc3-c3ccc4c(c3)oc3cc5c6ccccc6n(-c6ccccc6)c5cc34)n2)cc1]

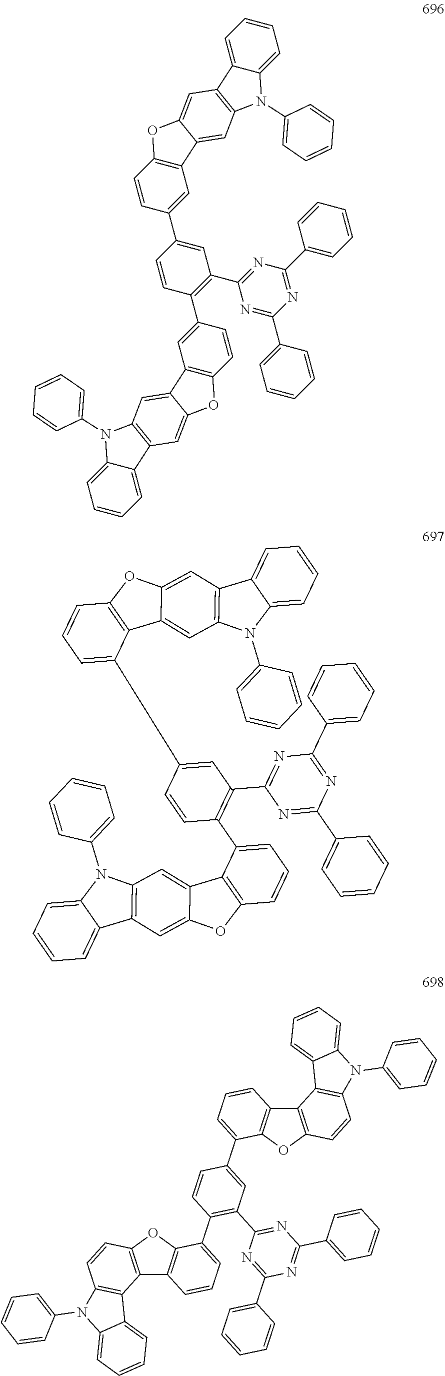 [SMILES: c1ccc(-c2nc(-c3ccccc3)nc(-c3cc(-c4ccc5oc6cc7c8ccccc8n(-c8ccccc8)c7cc6c5c4)ccc3-c3ccc4oc5cc6c7ccccc7n(-c7ccccc7)c6cc5c4c3)n2)cc1 ; c1ccc(-c2nc(-c3ccccc3)nc(-c3cc(-c4cccc5oc6cc7c8ccccc8n(-c8ccccc8)c7cc6c45)ccc3-c3cccc4oc5cc6c7ccccc7n(-c7ccccc7)c6cc5c34)n2)cc1 ; c1ccc(-c2nc(-c3ccccc3)nc(-c3cc(-c4cccc5c4oc4ccc6c(c7ccccc7n6-c6ccccc6)c45)ccc3-c3cccc4c3oc3ccc5c(c6ccccc6n5-c5ccccc5)c34)n2)cc1]

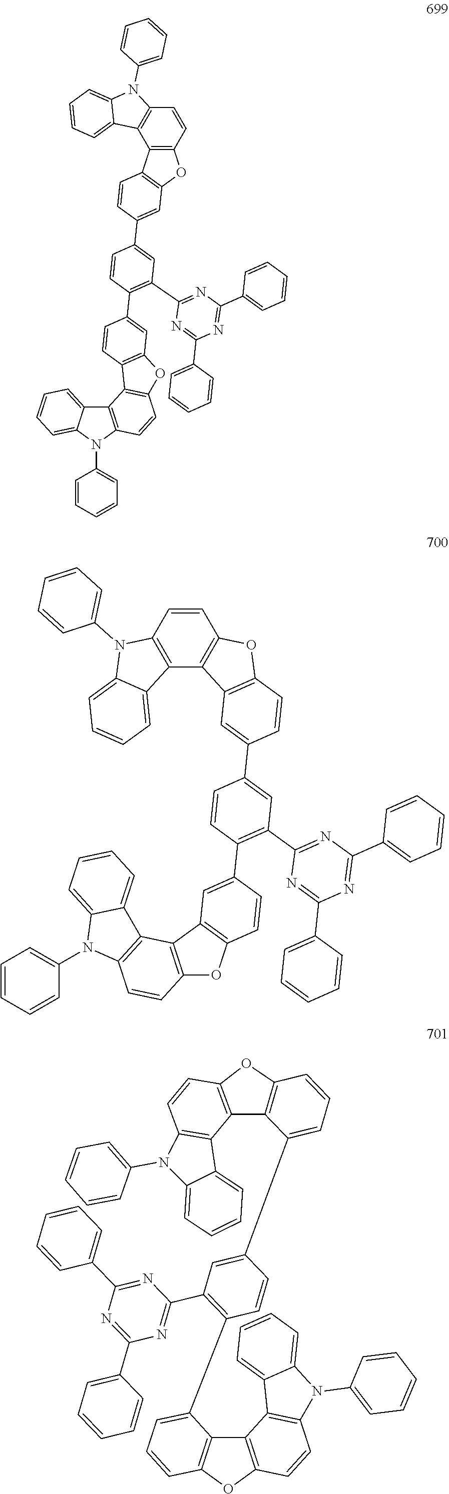 [SMILES: c1ccc(-c2nc(-c3ccccc3)nc(-c3cc(-c4ccc5c(c4)oc4ccc6c(c7ccccc7n6-c6ccccc6)c45)ccc3-c3ccc4c(c3)oc3ccc5c(c6ccccc6n5-c5ccccc5)c34)n2)cc1 ; c1ccc(-c2nc(-c3ccccc3)nc(-c3cc(-c4ccc5oc6ccc7c(c8ccccc8n7-c7ccccc7)c6c5c4)ccc3-c3ccc4oc5ccc6c(c7ccccc7n6-c6ccccc6)c5c4c3)n2)cc1 ; c1ccc(-c2nc(-c3ccccc3)nc(-c3cc(-c4cccc5oc6ccc7c(c8ccccc8n7-c7ccccc7)c6c45)ccc3-c3cccc4oc5ccc6c(c7ccccc7n6-c6ccccc6)c5c34)n2)cc1]

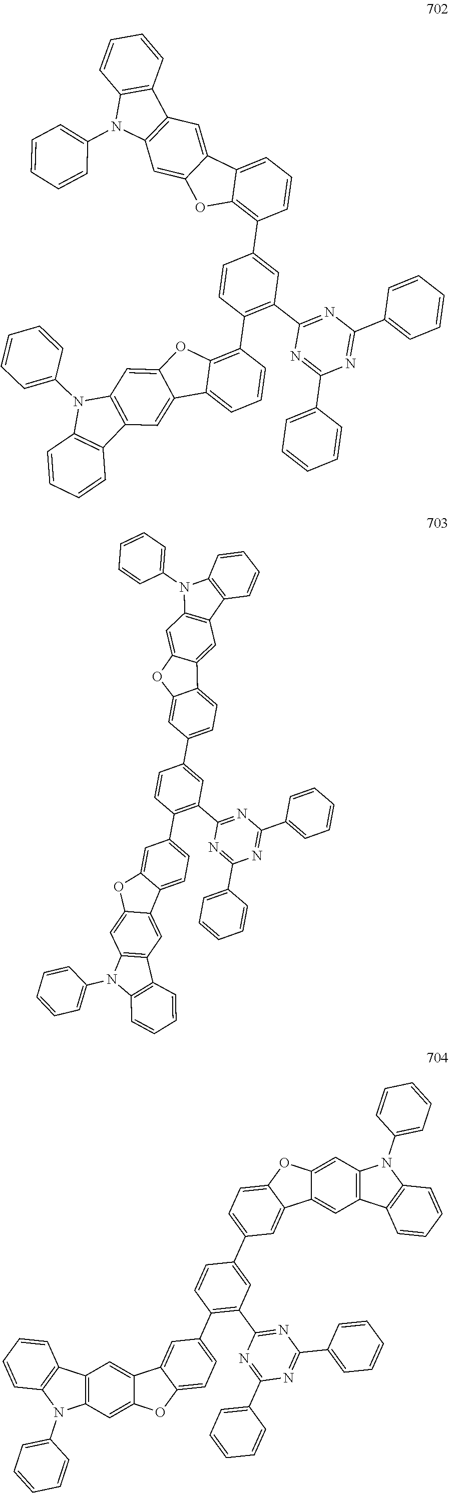 [SMILES: c1ccc(-c2nc(-c3ccccc3)nc(-c3cc(-c4cccc5c4oc4cc6c(cc45)c4ccccc4n6-c4ccccc4)ccc3-c3cccc4c3oc3cc5c(cc34)c3ccccc3n5-c3ccccc3)n2)cc1 ; c1ccc(-c2nc(-c3ccccc3)nc(-c3cc(-c4ccc5c(c4)oc4cc6c(cc45)c4ccccc4n6-c4ccccc4)ccc3-c3ccc4c(c3)oc3cc5c(cc34)c3ccccc3n5-c3ccccc3)n2)cc1 ; c1ccc(-c2nc(-c3ccccc3)nc(-c3cc(-c4ccc5oc6cc7c(cc6c5c4)c4ccccc4n7-c4ccccc4)ccc3-c3ccc4oc5cc6c(cc5c4c3)c3ccccc3n6-c3ccccc3)n2)cc1]

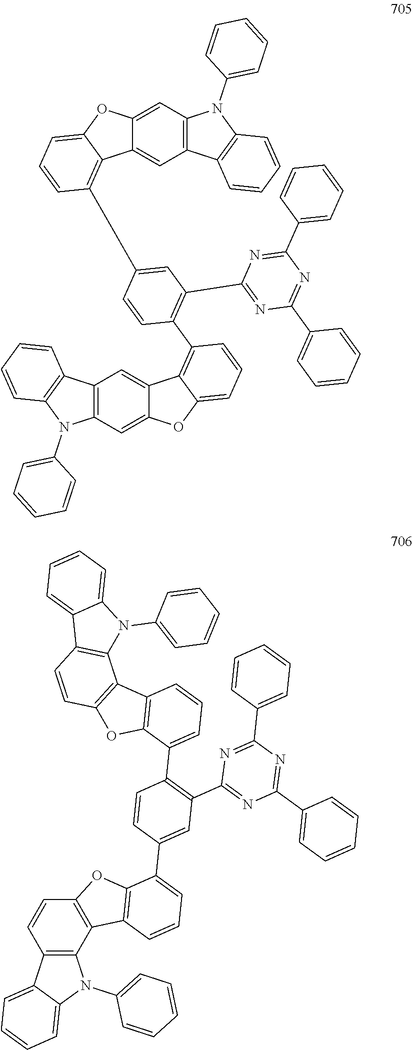

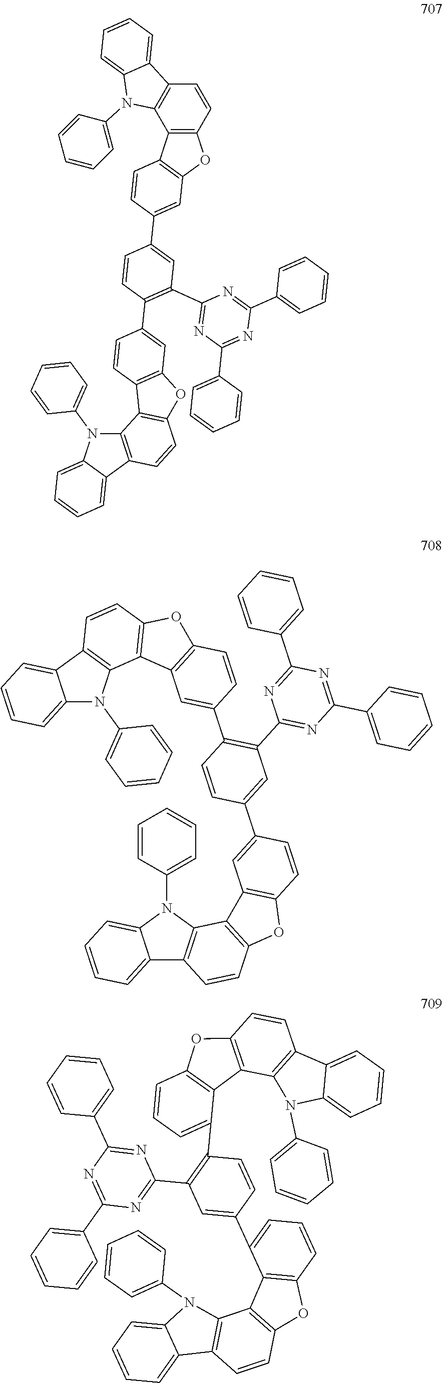

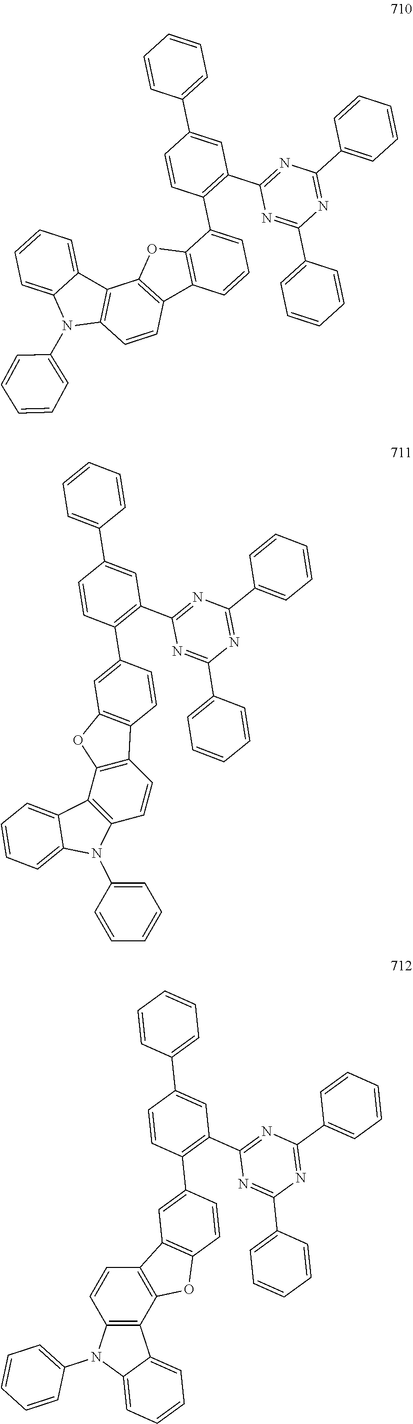 [SMILES: c1ccc(-c2ccc(-c3cccc4c3oc3c4ccc4c3c3ccccc3n4-c3ccccc3)c(-c3nc(-c4ccccc4)nc(-c4ccccc4)n3)c2)cc1 ; c1ccc(-c2ccc(-c3ccc4c(c3)oc3c4ccc4c3c3ccccc3n4-c3ccccc3)c(-c3nc(-c4ccccc4)nc(-c4ccccc4)n3)c2)cc1 ; c1ccc(-c2ccc(-c3ccc4oc5c(ccc6c5c5ccccc5n6-c5ccccc5)c4c3)c(-c3nc(-c4ccccc4)nc(-c4ccccc4)n3)c2)cc1]

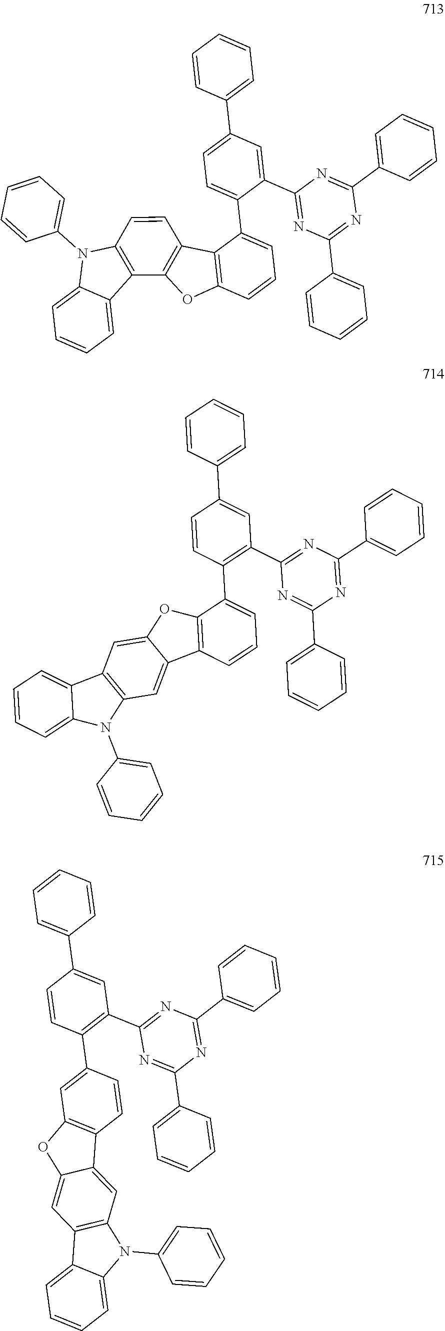 [SMILES: c1ccc(-c2ccc(-c3cccc4oc5c(ccc6c5c5ccccc5n6-c5ccccc5)c34)c(-c3nc(-c4ccccc4)nc(-c4ccccc4)n3)c2)cc1 ; c1ccc(-c2ccc(-c3cccc4c3oc3cc5c6ccccc6n(-c6ccccc6)c5cc34)c(-c3nc(-c4ccccc4)nc(-c4ccccc4)n3)c2)cc1 ; c1ccc(-c2ccc(-c3ccc4c(c3)oc3cc5c6ccccc6n(-c6ccccc6)c5cc34)c(-c3nc(-c4ccccc4)nc(-c4ccccc4)n3)c2)cc1]

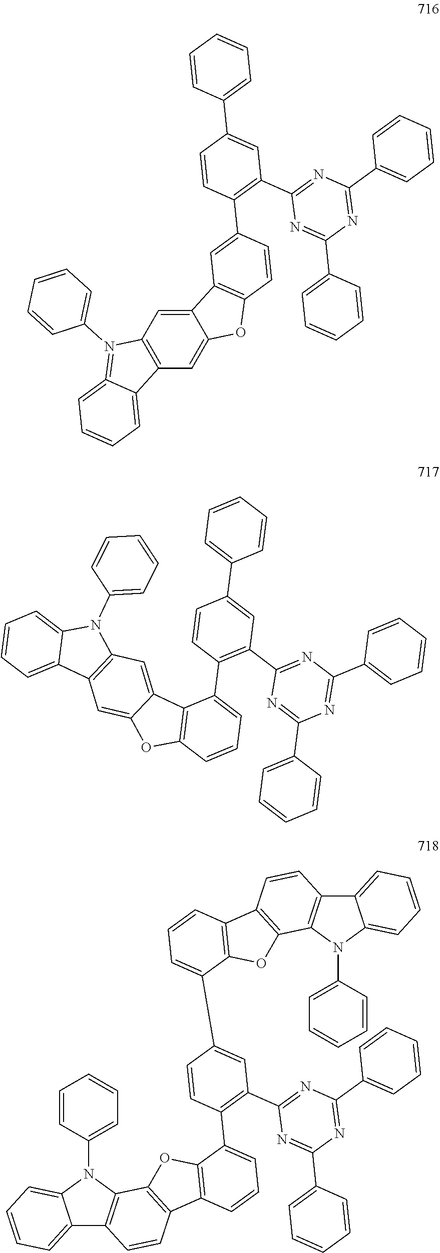

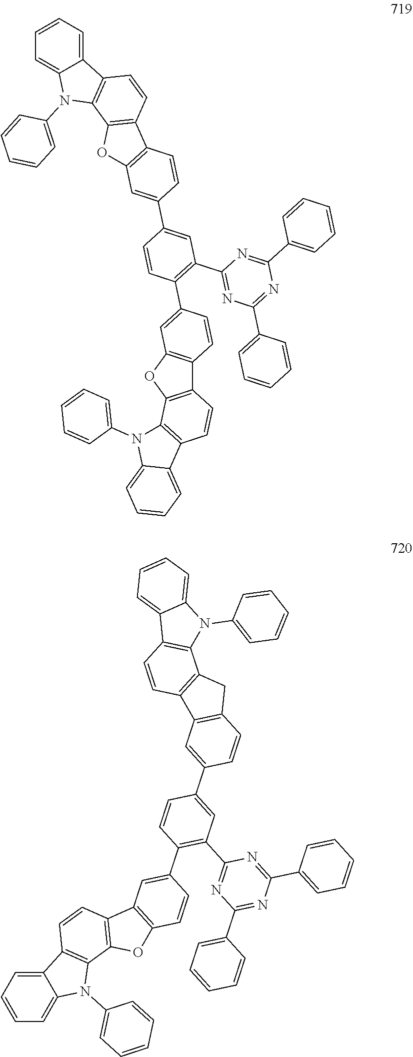 [SMILES: c1ccc(-c2nc(-c3ccccc3)nc(-c3cc(-c4ccc5c(c4)oc4c5ccc5c6ccccc6n(-c6ccccc6)c54)ccc3-c3ccc4c(c3)oc3c4ccc4c5ccccc5n(-c5ccccc5)c43)n2)cc1 ; c1ccc(-c2nc(-c3ccccc3)nc(-c3cc(-c4ccc5c(c4)-c4ccc6c7ccccc7n(-c7ccccc7)c6c4C5)ccc3-c3ccc4oc5c(ccc6c7ccccc7n(-c7ccccc7)c65)c4c3)n2)cc1]

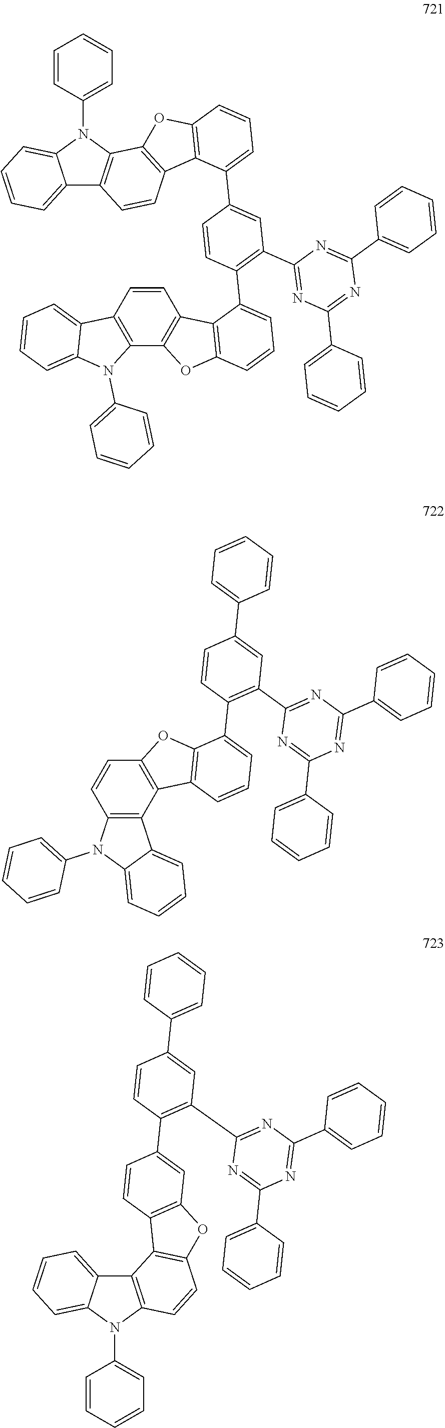

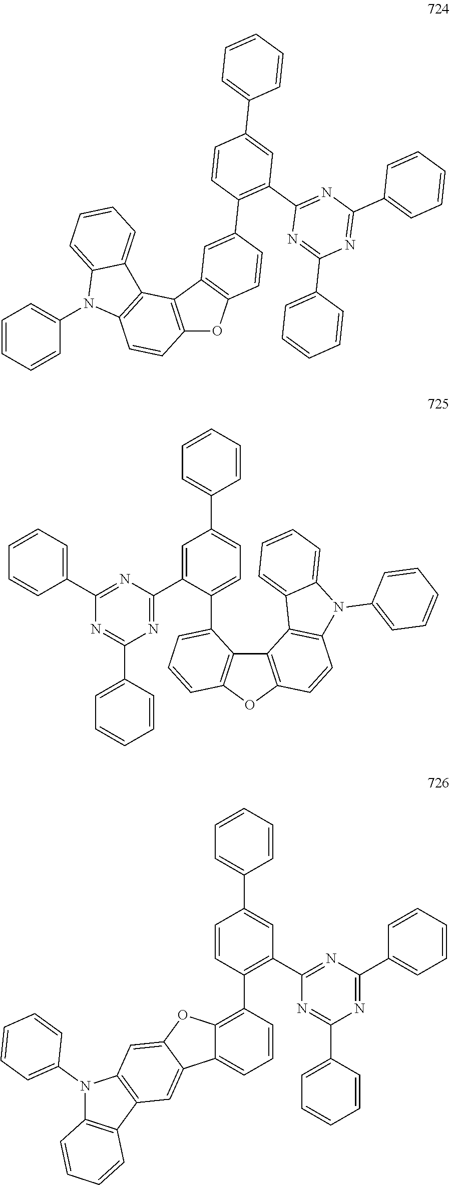 [SMILES: c1ccc(-c2ccc(-c3ccc4oc5ccc6c(c7ccccc7n6-c6ccccc6)c5c4c3)c(-c3nc(-c4ccccc4)nc(-c4ccccc4)n3)c2)cc1 ; c1ccc(-c2ccc(-c3cccc4oc5ccc6c(c7ccccc7n6-c6ccccc6)c5c34)c(-c3nc(-c4ccccc4)nc(-c4ccccc4)n3)c2)cc1 ; c1ccc(-c2ccc(-c3cccc4c3oc3cc5c(cc34)c3ccccc3n5-c3ccccc3)c(-c3nc(-c4ccccc4)nc(-c4ccccc4)n3)c2)cc1]

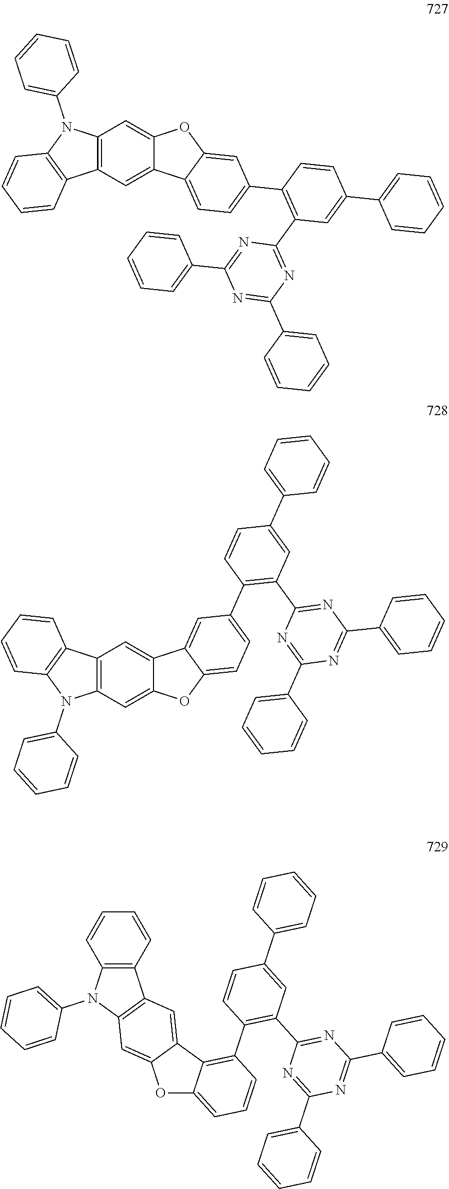

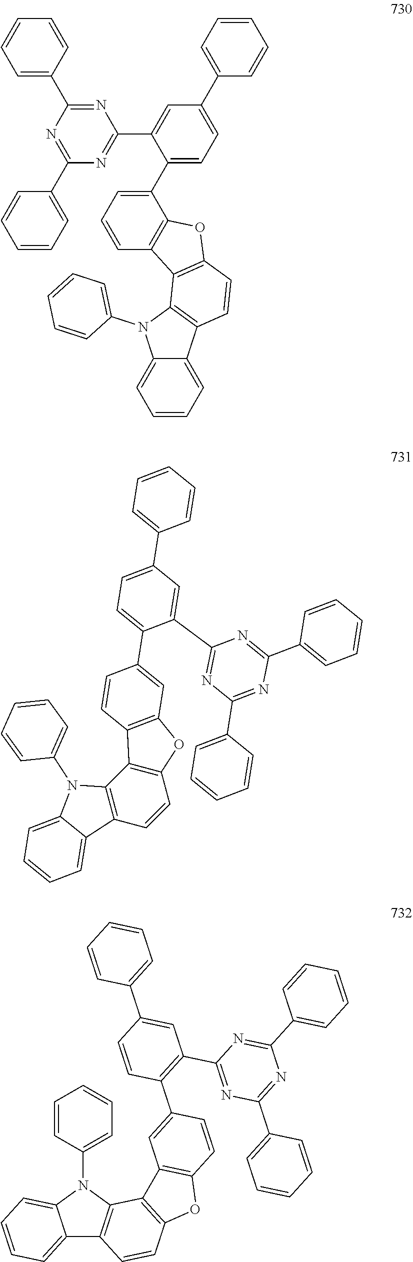 [SMILES: c1ccc(-c2ccc(-c3cccc4c3oc3ccc5c6ccccc6n(-c6ccccc6)c5c34)c(-c3nc(-c4ccccc4)nc(-c4ccccc4)n3)c2)cc1 ; c1ccc(-c2ccc(-c3ccc4c(c3)oc3ccc5c6ccccc6n(-c6ccccc6)c5c34)c(-c3nc(-c4ccccc4)nc(-c4ccccc4)n3)c2)cc1 ; c1ccc(-c2ccc(-c3ccc4oc5ccc6c7ccccc7n(-c7ccccc7)c6c5c4c3)c(-c3nc(-c4ccccc4)nc(-c4ccccc4)n3)c2)cc1]

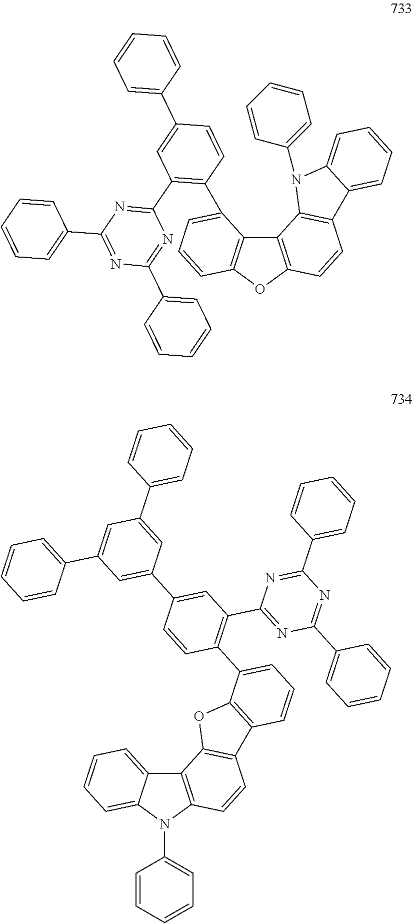 [SMILES: c1ccc(-c2ccc(-c3cccc4oc5ccc6c7ccccc7n(-c7ccccc7)c6c5c34)c(-c3nc(-c4ccccc4)nc(-c4ccccc4)n3)c2)cc1 ; c1ccc(-c2cc(-c3ccccc3)cc(-c3ccc(-c4cccc5c4oc4c5ccc5c4c4ccccc4n5-c4ccccc4)c(-c4nc(-c5ccccc5)nc(-c5ccccc5)n4)c3)c2)cc1]

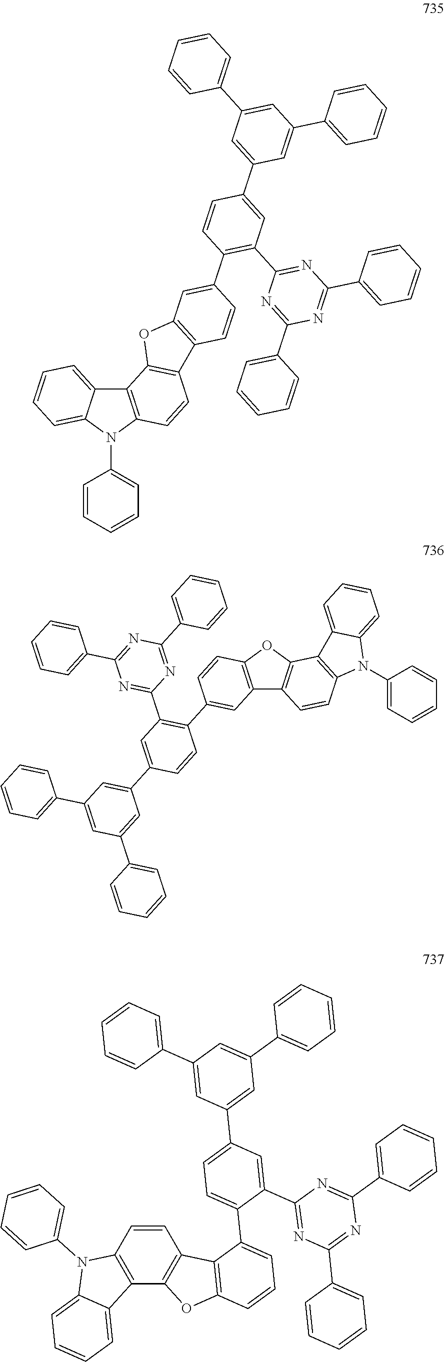 [SMILES: c1ccc(-c2cc(-c3ccccc3)cc(-c3ccc(-c4ccc5c(c4)oc4c5ccc5c4c4ccccc4n5-c4ccccc4)c(-c4nc(-c5ccccc5)nc(-c5ccccc5)n4)c3)c2)cc1 ; c1ccc(-c2cc(-c3ccccc3)cc(-c3ccc(-c4ccc5oc6c(ccc7c6c6ccccc6n7-c6ccccc6)c5c4)c(-c4nc(-c5ccccc5)nc(-c5ccccc5)n4)c3)c2)cc1 ; c1ccc(-c2cc(-c3ccccc3)cc(-c3ccc(-c4cccc5oc6c(ccc7c6c6ccccc6n7-c6ccccc6)c45)c(-c4nc(-c5ccccc5)nc(-c5ccccc5)n4)c3)c2)cc1]

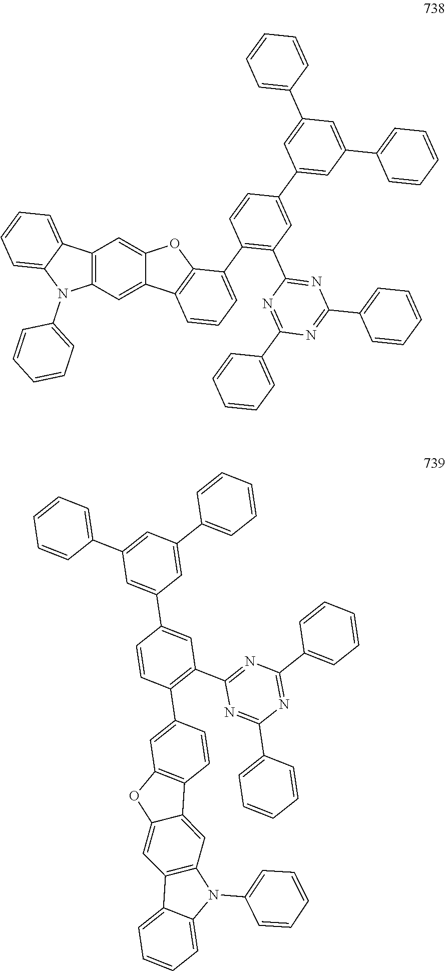 [SMILES: c1ccc(-c2cc(-c3ccccc3)cc(-c3ccc(-c4cccc5c4oc4cc6c7ccccc7n(-c7ccccc7)c6cc45)c(-c4nc(-c5ccccc5)nc(-c5ccccc5)n4)c3)c2)cc1 ; c1ccc(-c2cc(-c3ccccc3)cc(-c3ccc(-c4ccc5c(c4)oc4cc6c7ccccc7n(-c7ccccc7)c6cc45)c(-c4nc(-c5ccccc5)nc(-c5ccccc5)n4)c3)c2)cc1]

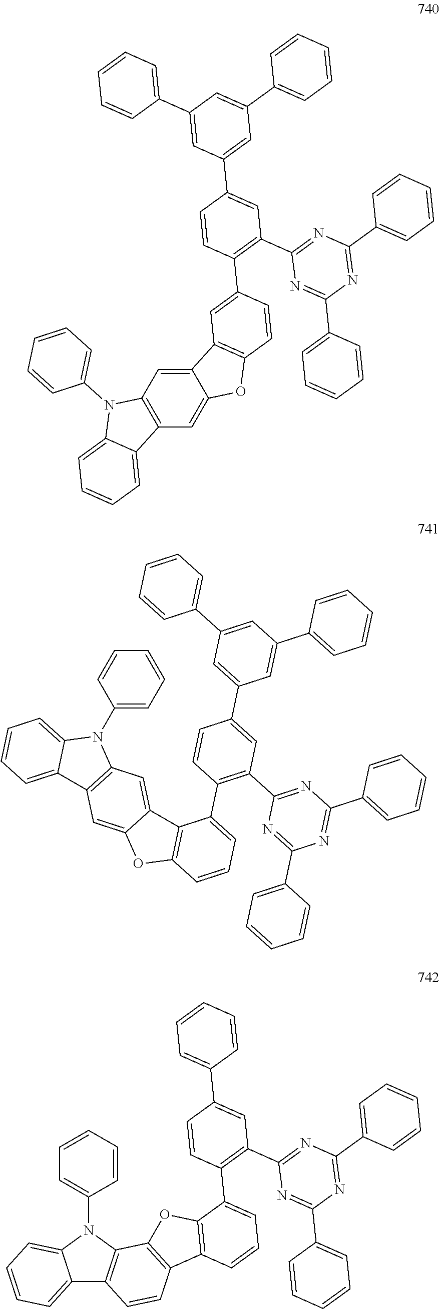 [SMILES: c1ccc(-c2cc(-c3ccccc3)cc(-c3ccc(-c4ccc5oc6cc7c8ccccc8n(-c8ccccc8)c7cc6c5c4)c(-c4nc(-c5ccccc5)nc(-c5ccccc5)n4)c3)c2)cc1 ; c1ccc(-c2cc(-c3ccccc3)cc(-c3ccc(-c4cccc5oc6cc7c8ccccc8n(-c8ccccc8)c7cc6c45)c(-c4nc(-c5ccccc5)nc(-c5ccccc5)n4)c3)c2)cc1 ; c1ccc(-c2ccc(-c3cccc4c3oc3c4ccc4c5ccccc5n(-c5ccccc5)c43)c(-c3nc(-c4ccccc4)nc(-c4ccccc4)n3)c2)cc1]

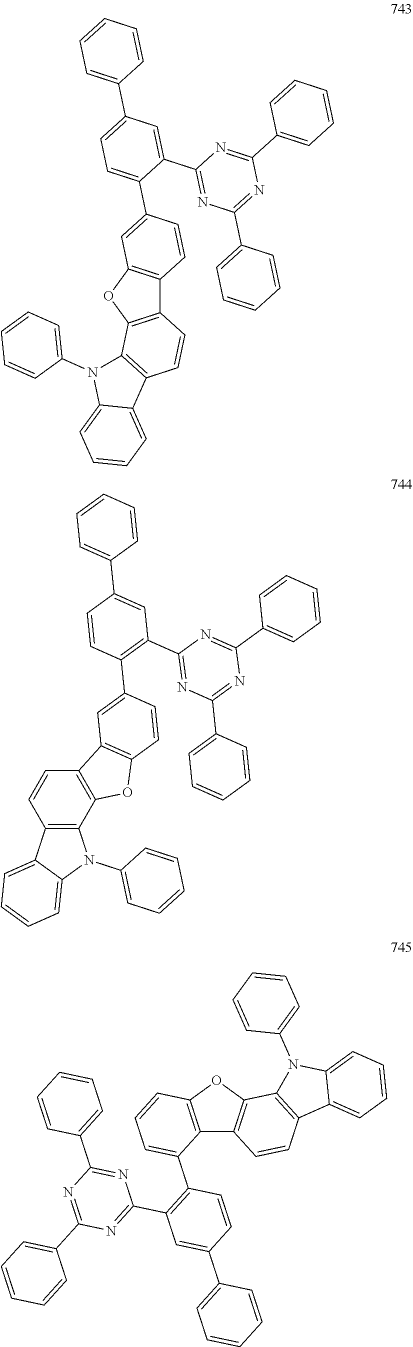

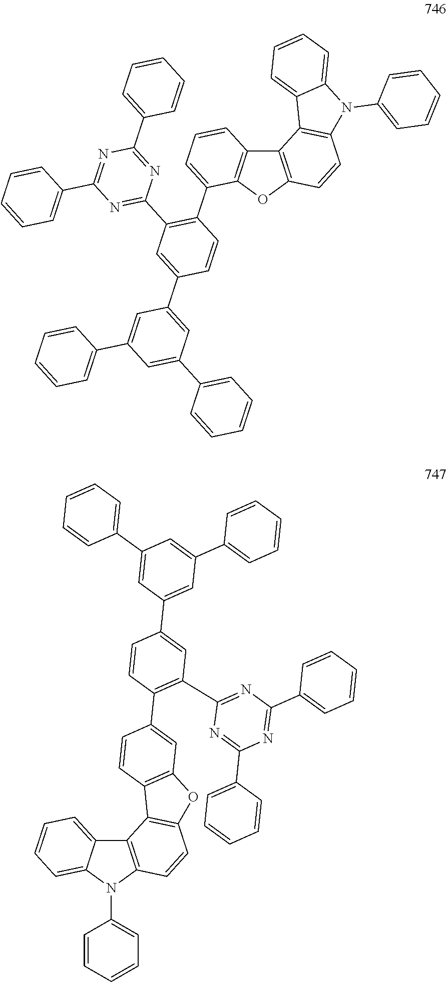 [SMILES: c1ccc(-c2cc(-c3ccccc3)cc(-c3ccc(-c4cccc5c4oc4ccc6c(c7ccccc7n6-c6ccccc6)c45)c(-c4nc(-c5ccccc5)nc(-c5ccccc5)n4)c3)c2)cc1 ; c1ccc(-c2cc(-c3ccccc3)cc(-c3ccc(-c4ccc5c(c4)oc4ccc6c(c7ccccc7n6-c6ccccc6)c45)c(-c4nc(-c5ccccc5)nc(-c5ccccc5)n4)c3)c2)cc1]

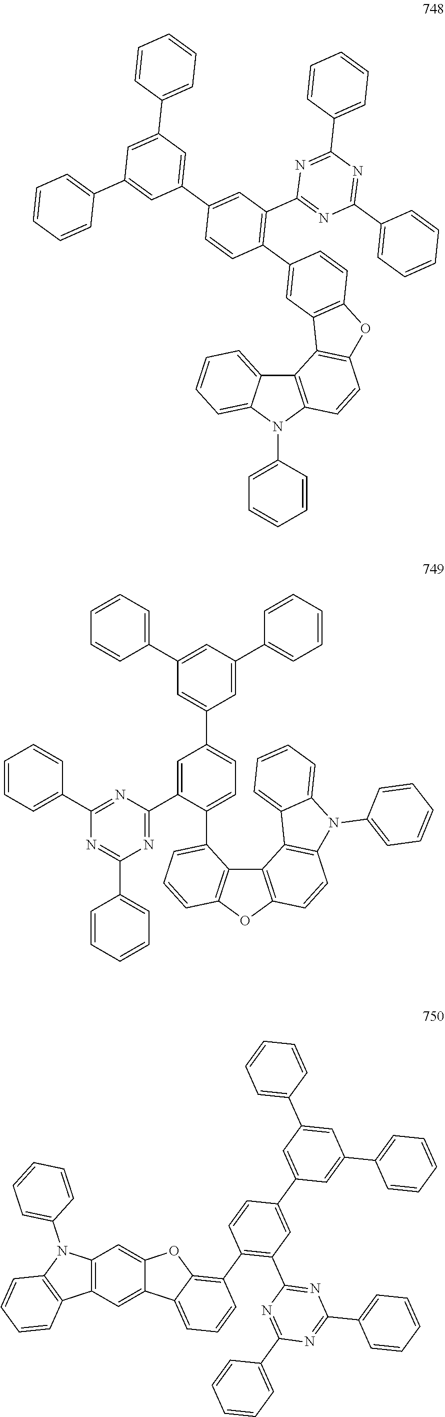 [SMILES: c1ccc(-c2cc(-c3ccccc3)cc(-c3ccc(-c4ccc5oc6ccc7c(c8ccccc8n7-c7ccccc7)c6c5c4)c(-c4nc(-c5ccccc5)nc(-c5ccccc5)n4)c3)c2)cc1 ; c1ccc(-c2cc(-c3ccccc3)cc(-c3ccc(-c4cccc5oc6ccc7c(c8ccccc8n7-c7ccccc7)c6c45)c(-c4nc(-c5ccccc5)nc(-c5ccccc5)n4)c3)c2)cc1 ; c1ccc(-c2cc(-c3ccccc3)cc(-c3ccc(-c4cccc5c4oc4cc6c(cc45)c4ccccc4n6-c4ccccc4)c(-c4nc(-c5ccccc5)nc(-c5ccccc5)n4)c3)c2)cc1]

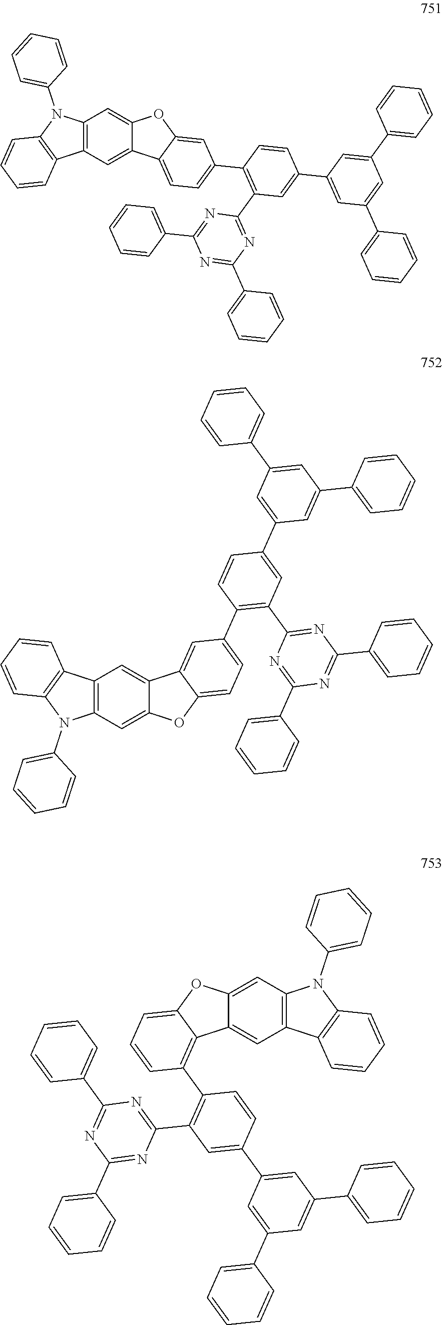 [SMILES: c1ccc(-c2cc(-c3ccccc3)cc(-c3ccc(-c4ccc5c(c4)oc4cc6c(cc45)c4ccccc4n6-c4ccccc4)c(-c4nc(-c5ccccc5)nc(-c5ccccc5)n4)c3)c2)cc1 ; c1ccc(-c2cc(-c3ccccc3)cc(-c3ccc(-c4ccc5oc6cc7c(cc6c5c4)c4ccccc4n7-c4ccccc4)c(-c4nc(-c5ccccc5)nc(-c5ccccc5)n4)c3)c2)cc1 ; c1ccc(-c2cc(-c3ccccc3)cc(-c3ccc(-c4cccc5oc6cc7c(cc6c45)c4ccccc4n7-c4ccccc4)c(-c4nc(-c5ccccc5)nc(-c5ccccc5)n4)c3)c2)cc1]

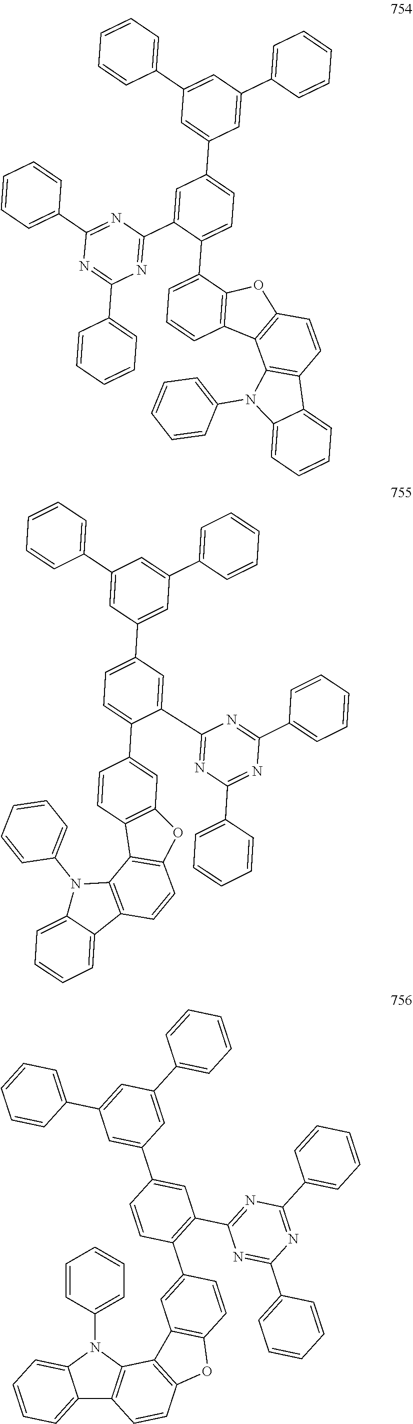 [SMILES: c1ccc(-c2cc(-c3ccccc3)cc(-c3ccc(-c4cccc5c4oc4ccc6c7ccccc7n(-c7ccccc7)c6c45)c(-c4nc(-c5ccccc5)nc(-c5ccccc5)n4)c3)c2)cc1 ; c1ccc(-c2cc(-c3ccccc3)cc(-c3ccc(-c4ccc5c(c4)oc4ccc6c7ccccc7n(-c7ccccc7)c6c45)c(-c4nc(-c5ccccc5)nc(-c5ccccc5)n4)c3)c2)cc1 ; c1ccc(-c2cc(-c3ccccc3)cc(-c3ccc(-c4ccc5oc6ccc7c8ccccc8n(-c8ccccc8)c7c6c5c4)c(-c4nc(-c5ccccc5)nc(-c5ccccc5)n4)c3)c2)cc1]

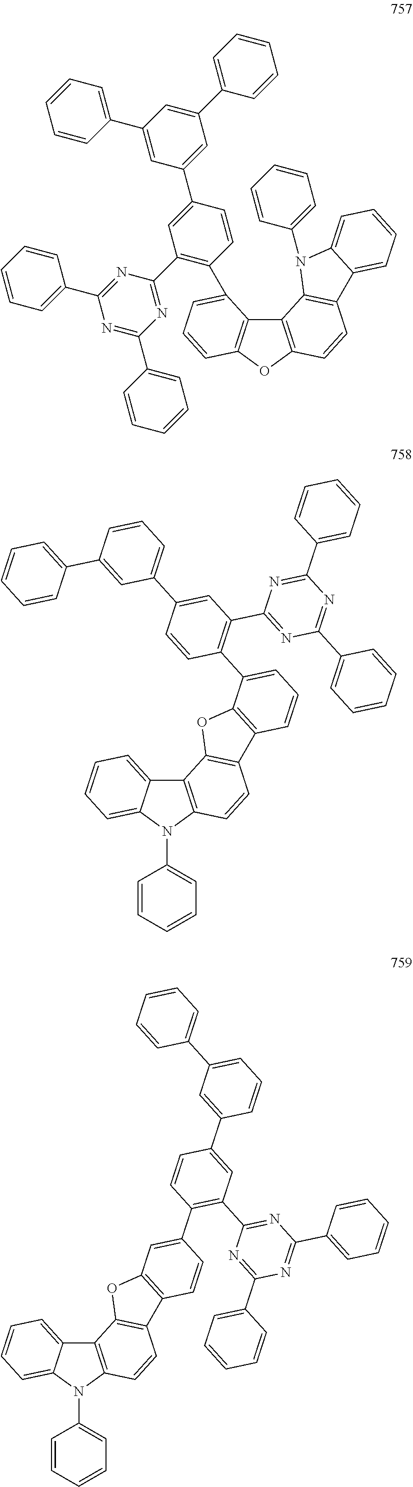 [SMILES: c1ccc(-c2cc(-c3ccccc3)cc(-c3ccc(-c4cccc5oc6ccc7c8ccccc8n(-c8ccccc8)c7c6c45)c(-c4nc(-c5ccccc5)nc(-c5ccccc5)n4)c3)c2)cc1 ; c1ccc(-c2cccc(-c3ccc(-c4cccc5c4oc4c5ccc5c4c4ccccc4n5-c4ccccc4)c(-c4nc(-c5ccccc5)nc(-c5ccccc5)n4)c3)c2)cc1 ; c1ccc(-c2cccc(-c3ccc(-c4ccc5c(c4)oc4c5ccc5c4c4ccccc4n5-c4ccccc4)c(-c4nc(-c5ccccc5)nc(-c5ccccc5)n4)c3)c2)cc1]

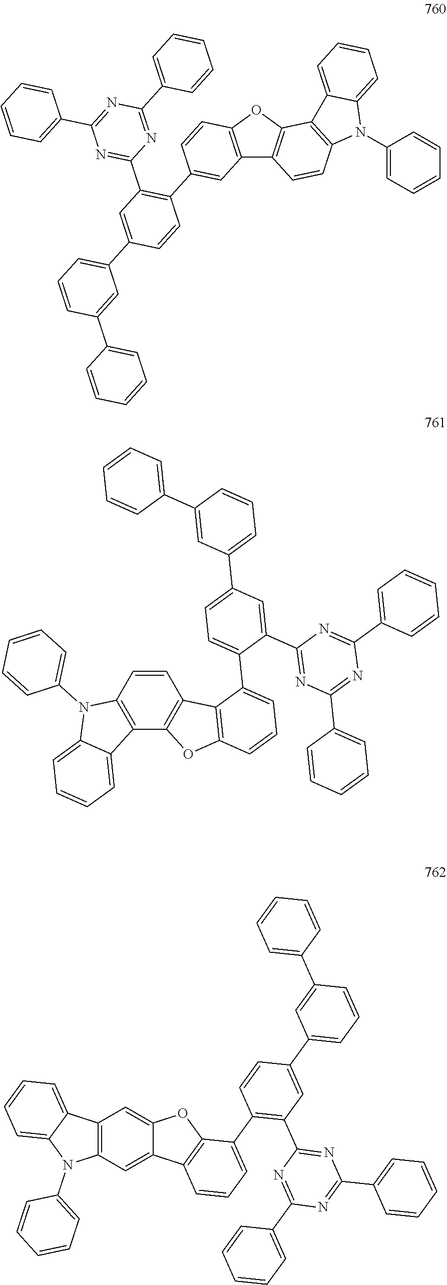

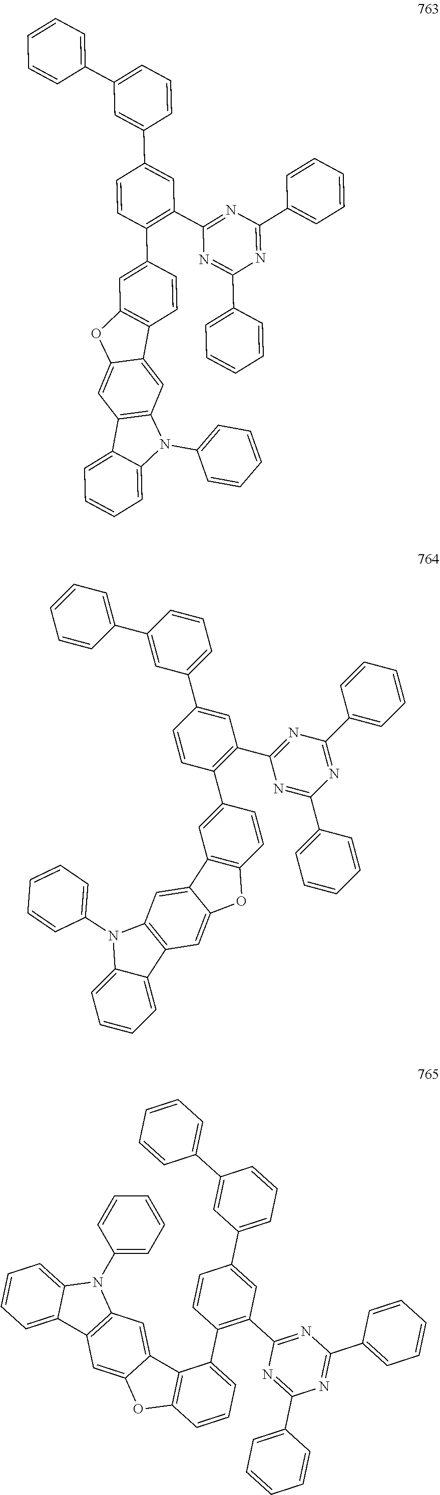 [SMILES: c1ccc(-c2cccc(-c3ccc(-c4ccc5c(c4)oc4cc6c7ccccc7n(-c7ccccc7)c6cc45)c(-c4nc(-c5ccccc5)nc(-c5ccccc5)n4)c3)c2)cc1 ; c1ccc(-c2cccc(-c3ccc(-c4ccc5oc6cc7c8ccccc8n(-c8ccccc8)c7cc6c5c4)c(-c4nc(-c5ccccc5)nc(-c5ccccc5)n4)c3)c2)cc1 ; c1ccc(-c2cccc(-c3ccc(-c4cccc5oc6cc7c8ccccc8n(-c8ccccc8)c7cc6c45)c(-c4nc(-c5ccccc5)nc(-c5ccccc5)n4)c3)c2)cc1]

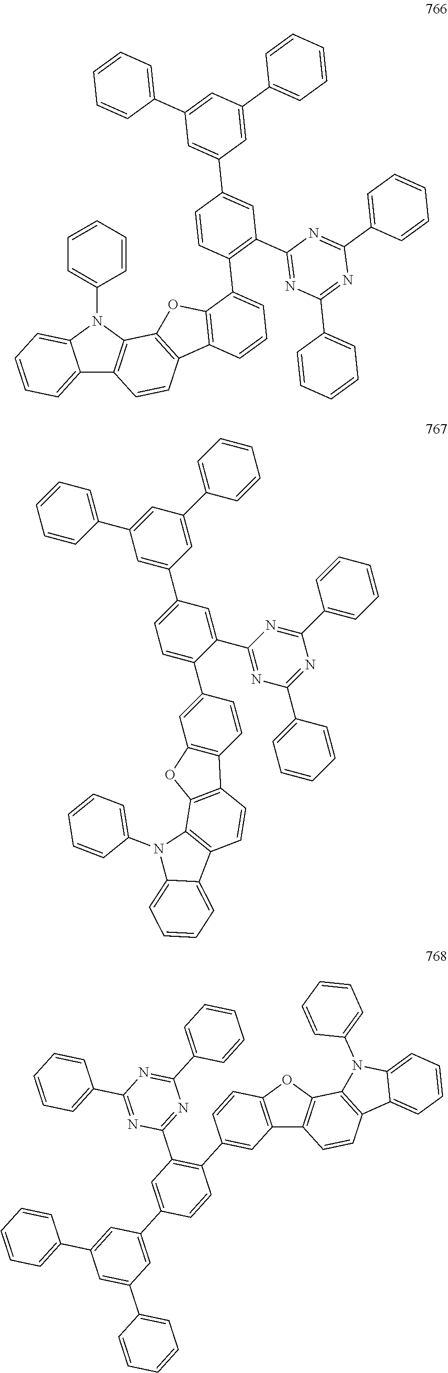 [SMILES: c1ccc(-c2cc(-c3ccccc3)cc(-c3ccc(-c4cccc5c4oc4c5ccc5c6ccccc6n(-c6ccccc6)c54)c(-c4nc(-c5ccccc5)nc(-c5ccccc5)n4)c3)c2)cc1 ; c1ccc(-c2cc(-c3ccccc3)cc(-c3ccc(-c4ccc5c(c4)oc4c5ccc5c6ccccc6n(-c6ccccc6)c54)c(-c4nc(-c5ccccc5)nc(-c5ccccc5)n4)c3)c2)cc1 ; c1ccc(-c2cc(-c3ccccc3)cc(-c3ccc(-c4ccc5oc6c(ccc7c8ccccc8n(-c8ccccc8)c76)c5c4)c(-c4nc(-c5ccccc5)nc(-c5ccccc5)n4)c3)c2)cc1]

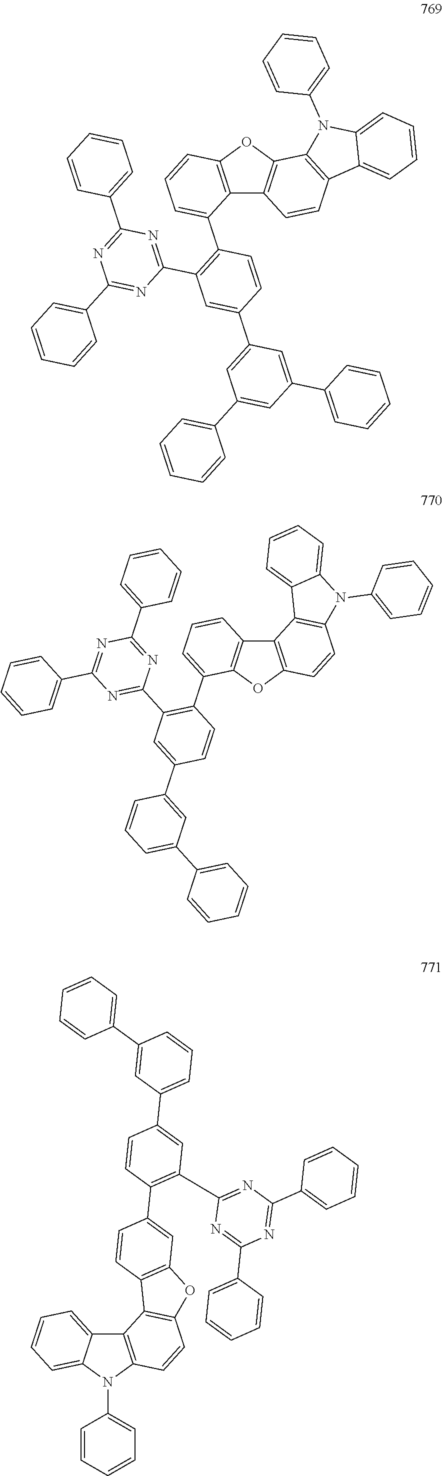 [SMILES: c1ccc(-c2cc(-c3ccccc3)cc(-c3ccc(-c4cccc5oc6c(ccc7c8ccccc8n(-c8ccccc8)c76)c45)c(-c4nc(-c5ccccc5)nc(-c5ccccc5)n4)c3)c2)cc1 ; c1ccc(-c2cccc(-c3ccc(-c4cccc5c4oc4ccc6c(c7ccccc7n6-c6ccccc6)c45)c(-c4nc(-c5ccccc5)nc(-c5ccccc5)n4)c3)c2)cc1 ; c1ccc(-c2cccc(-c3ccc(-c4ccc5c(c4)oc4ccc6c(c7ccccc7n6-c6ccccc6)c45)c(-c4nc(-c5ccccc5)nc(-c5ccccc5)n4)c3)c2)cc1]

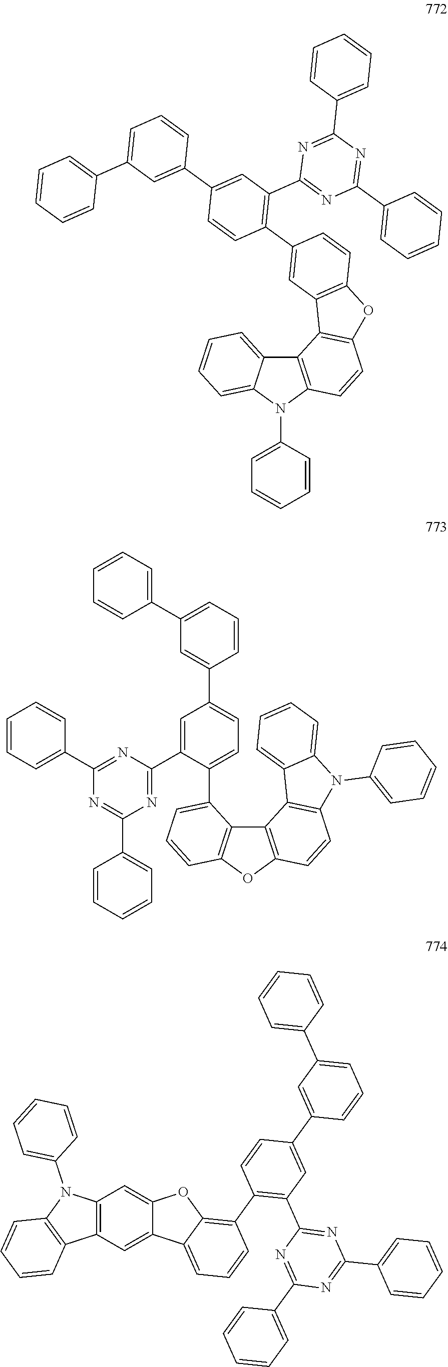 [SMILES: c1ccc(-c2cccc(-c3ccc(-c4ccc5oc6ccc7c(c8ccccc8n7-c7ccccc7)c6c5c4)c(-c4nc(-c5ccccc5)nc(-c5ccccc5)n4)c3)c2)cc1 ; c1ccc(-c2cccc(-c3ccc(-c4cccc5oc6ccc7c(c8ccccc8n7-c7ccccc7)c6c45)c(-c4nc(-c5ccccc5)nc(-c5ccccc5)n4)c3)c2)cc1 ; c1ccc(-c2cccc(-c3ccc(-c4cccc5c4oc4cc6c(cc45)c4ccccc4n6-c4ccccc4)c(-c4nc(-c5ccccc5)nc(-c5ccccc5)n4)c3)c2)cc1]

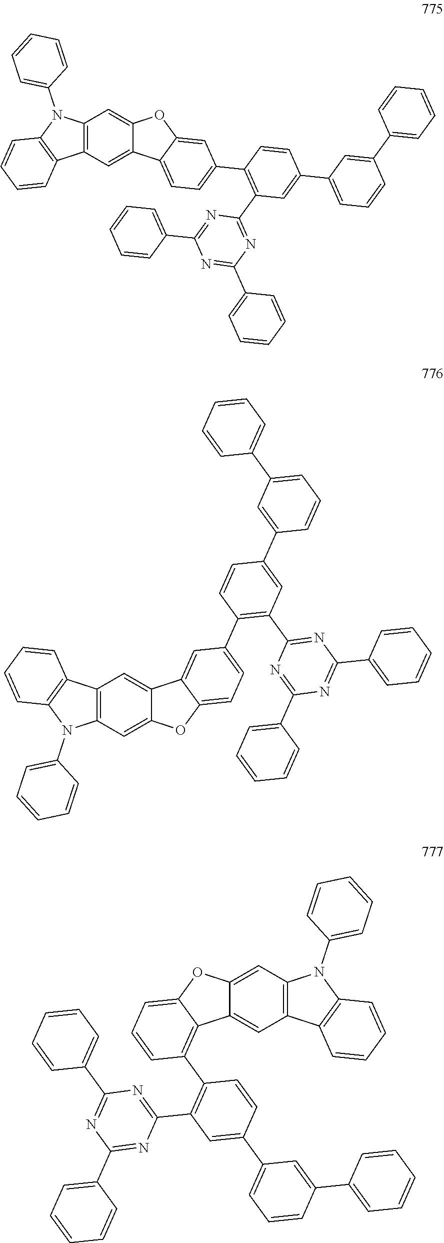 [SMILES: c1ccc(-c2cccc(-c3ccc(-c4ccc5c(c4)oc4cc6c(cc45)c4ccccc4n6-c4ccccc4)c(-c4nc(-c5ccccc5)nc(-c5ccccc5)n4)c3)c2)cc1 ; c1ccc(-c2cccc(-c3ccc(-c4ccc5oc6cc7c(cc6c5c4)c4ccccc4n7-c4ccccc4)c(-c4nc(-c5ccccc5)nc(-c5ccccc5)n4)c3)c2)cc1 ; c1ccc(-c2cccc(-c3ccc(-c4cccc5oc6cc7c(cc6c45)c4ccccc4n7-c4ccccc4)c(-c4nc(-c5ccccc5)nc(-c5ccccc5)n4)c3)c2)cc1]

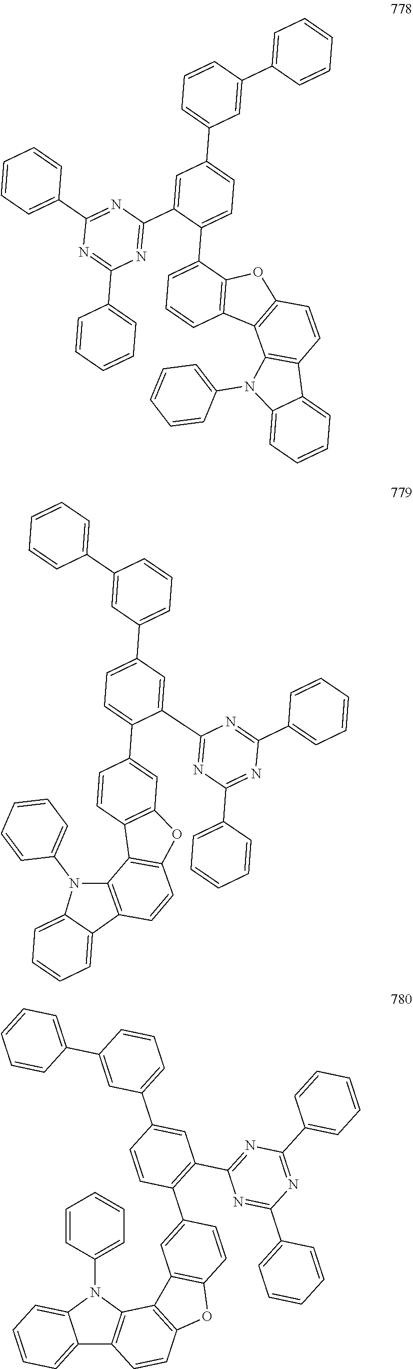

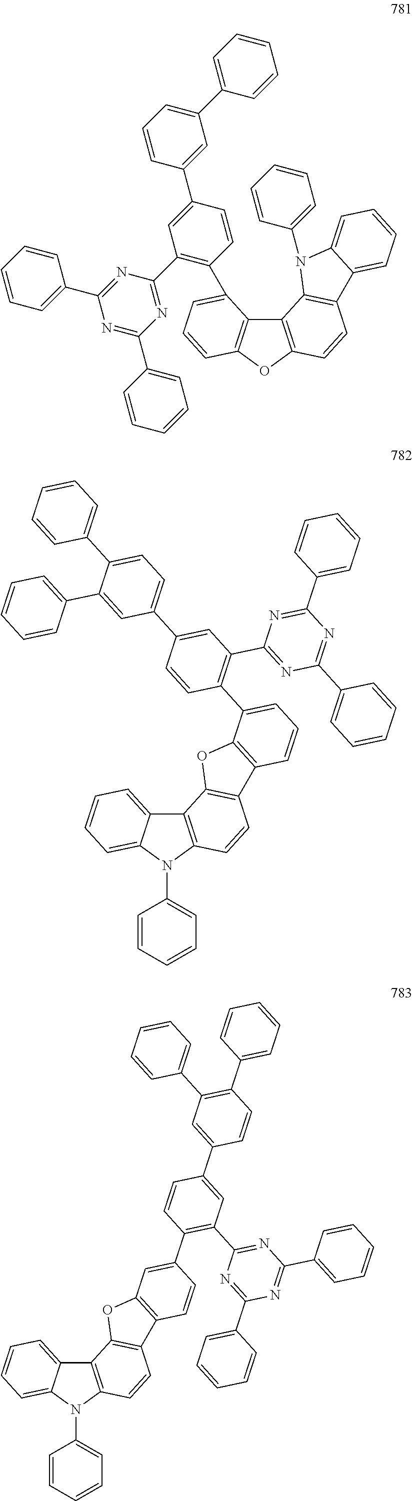 [SMILES: c1ccc(-c2cccc(-c3ccc(-c4cccc5oc6ccc7c8ccccc8n(-c8ccccc8)c7c6c45)c(-c4nc(-c5ccccc5)nc(-c5ccccc5)n4)c3)c2)cc1 ; c1ccc(-c2nc(-c3ccccc3)nc(-c3cc(-c4ccc(-c5ccccc5)c(-c5ccccc5)c4)ccc3-c3cccc4c3oc3c4ccc4c3c3ccccc3n4-c3ccccc3)n2)cc1 ; c1ccc(-c2nc(-c3ccccc3)nc(-c3cc(-c4ccc(-c5ccccc5)c(-c5ccccc5)c4)ccc3-c3ccc4c(c3)oc3c4ccc4c3c3ccccc3n4-c3ccccc3)n2)cc1]

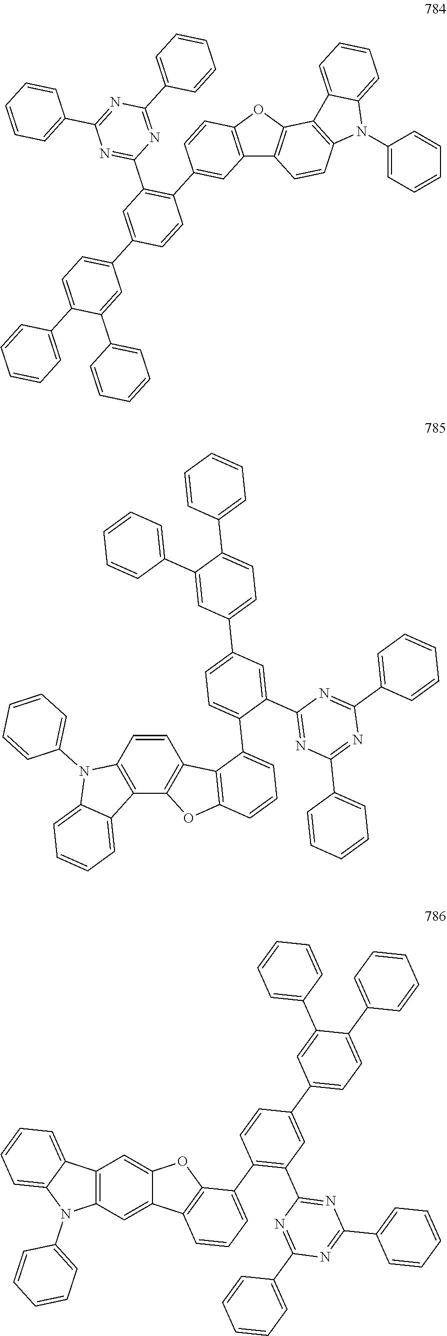 [SMILES: c1ccc(-c2nc(-c3ccccc3)nc(-c3cc(-c4ccc(-c5ccccc5)c(-c5ccccc5)c4)ccc3-c3ccc4oc5c(ccc6c5c5ccccc5n6-c5ccccc5)c4c3)n2)cc1 ; c1ccc(-c2nc(-c3ccccc3)nc(-c3cc(-c4ccc(-c5ccccc5)c(-c5ccccc5)c4)ccc3-c3cccc4oc5c(ccc6c5c5ccccc5n6-c5ccccc5)c34)n2)cc1 ; c1ccc(-c2nc(-c3ccccc3)nc(-c3cc(-c4ccc(-c5ccccc5)c(-c5ccccc5)c4)ccc3-c3cccc4c3oc3cc5c6ccccc6n(-c6ccccc6)c5cc34)n2)cc1]

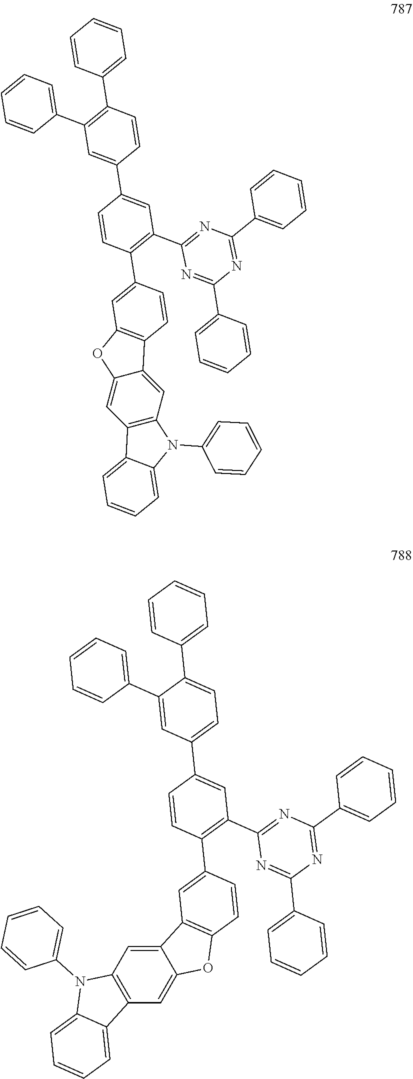 [SMILES: c1ccc(-c2nc(-c3ccccc3)nc(-c3cc(-c4ccc(-c5ccccc5)c(-c5ccccc5)c4)ccc3-c3ccc4c(c3)oc3cc5c6ccccc6n(-c6ccccc6)c5cc34)n2)cc1 ; c1ccc(-c2nc(-c3ccccc3)nc(-c3cc(-c4ccc(-c5ccccc5)c(-c5ccccc5)c4)ccc3-c3ccc4oc5cc6c7ccccc7n(-c7ccccc7)c6cc5c4c3)n2)cc1]

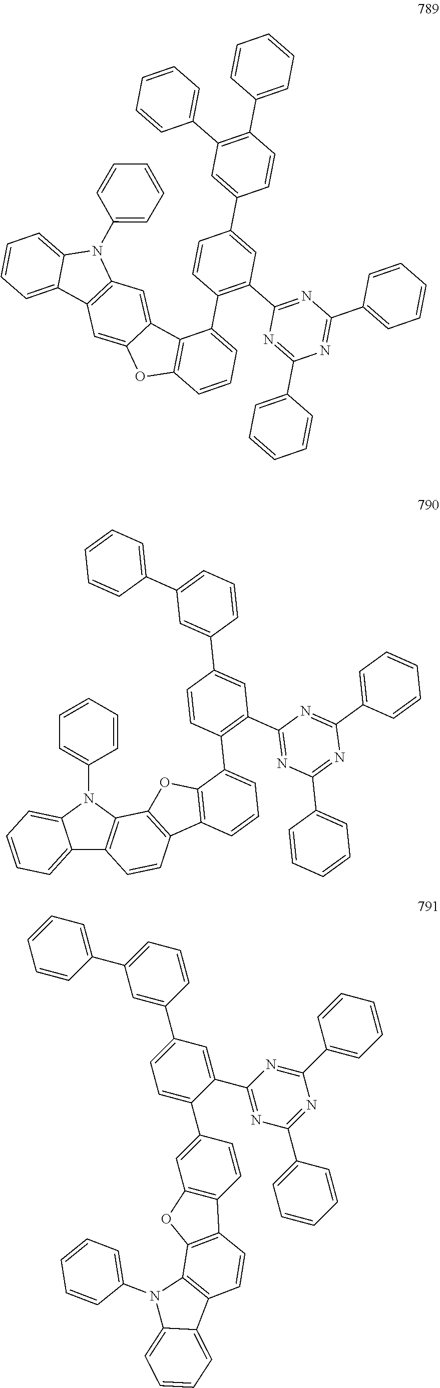

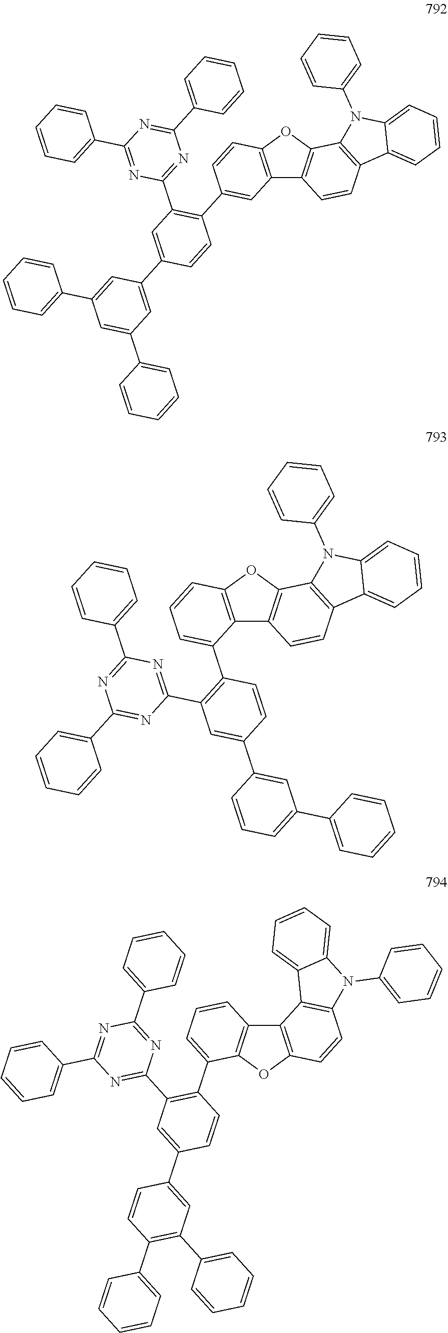 [SMILES: c1ccc(-c2cc(-c3ccccc3)cc(-c3ccc(-c4ccc5oc6c(ccc7c8ccccc8n(-c8ccccc8)c76)c5c4)c(-c4nc(-c5ccccc5)nc(-c5ccccc5)n4)c3)c2)cc1 ; c1ccc(-c2cccc(-c3ccc(-c4cccc5oc6c(ccc7c8ccccc8n(-c8ccccc8)c76)c45)c(-c4nc(-c5ccccc5)nc(-c5ccccc5)n4)c3)c2)cc1 ; c1ccc(-c2nc(-c3ccccc3)nc(-c3cc(-c4ccc(-c5ccccc5)c(-c5ccccc5)c4)ccc3-c3cccc4c3oc3ccc5c(c6ccccc6n5-c5ccccc5)c34)n2)cc1]

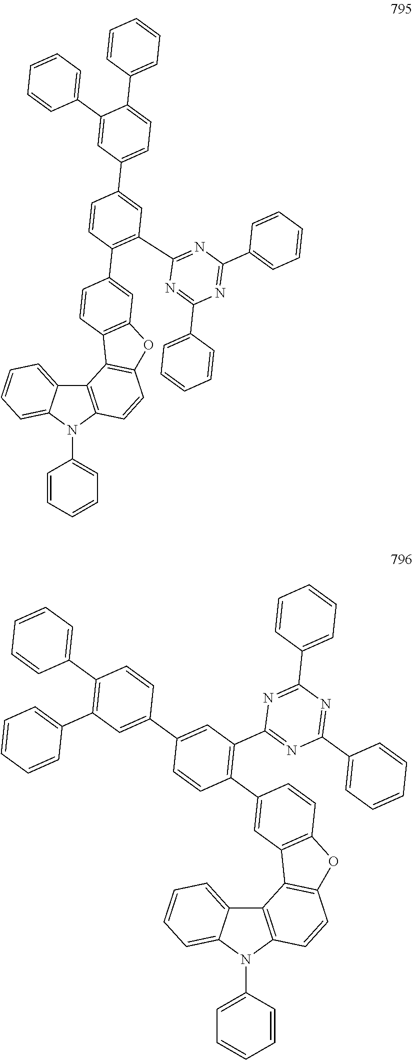 [SMILES: c1ccc(-c2nc(-c3ccccc3)nc(-c3cc(-c4ccc(-c5ccccc5)c(-c5ccccc5)c4)ccc3-c3ccc4c(c3)oc3ccc5c(c6ccccc6n5-c5ccccc5)c34)n2)cc1 ; c1ccc(-c2nc(-c3ccccc3)nc(-c3cc(-c4ccc(-c5ccccc5)c(-c5ccccc5)c4)ccc3-c3ccc4oc5ccc6c(c7ccccc7n6-c6ccccc6)c5c4c3)n2)cc1]

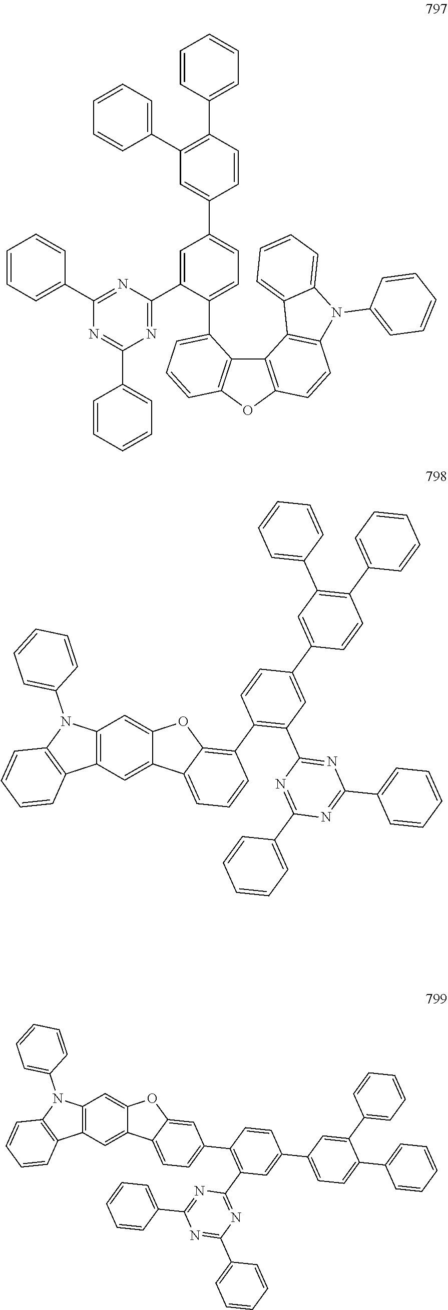 [SMILES: c1ccc(-c2nc(-c3ccccc3)nc(-c3cc(-c4ccc(-c5ccccc5)c(-c5ccccc5)c4)ccc3-c3cccc4oc5ccc6c(c7ccccc7n6-c6ccccc6)c5c34)n2)cc1 ; c1ccc(-c2nc(-c3ccccc3)nc(-c3cc(-c4ccc(-c5ccccc5)c(-c5ccccc5)c4)ccc3-c3cccc4c3oc3cc5c(cc34)c3ccccc3n5-c3ccccc3)n2)cc1 ; c1ccc(-c2nc(-c3ccccc3)nc(-c3cc(-c4ccc(-c5ccccc5)c(-c5ccccc5)c4)ccc3-c3ccc4c(c3)oc3cc5c(cc34)c3ccccc3n5-c3ccccc3)n2)cc1]

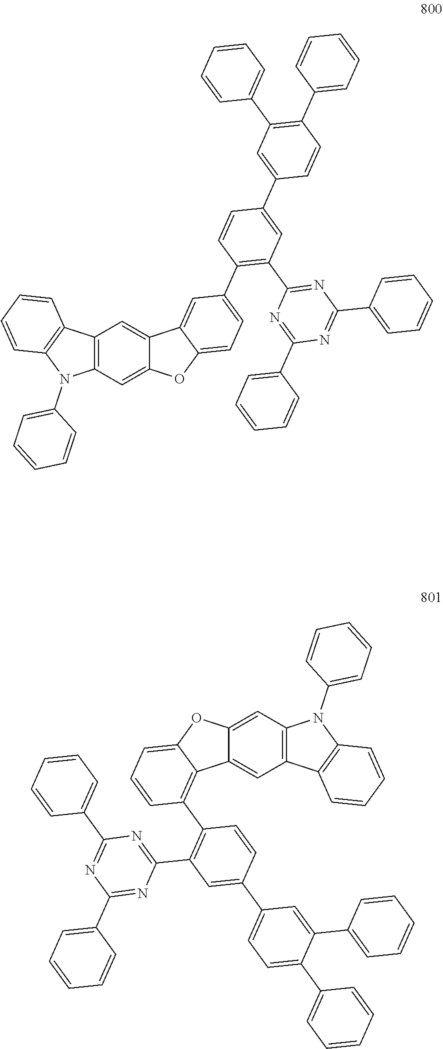 [SMILES: c1ccc(-c2nc(-c3ccccc3)nc(-c3cc(-c4ccc(-c5ccccc5)c(-c5ccccc5)c4)ccc3-c3ccc4oc5cc6c(cc5c4c3)c3ccccc3n6-c3ccccc3)n2)cc1 ; c1ccc(-c2nc(-c3ccccc3)nc(-c3cc(-c4ccc(-c5ccccc5)c(-c5ccccc5)c4)ccc3-c3cccc4oc5cc6c(cc5c34)c3ccccc3n6-c3ccccc3)n2)cc1]

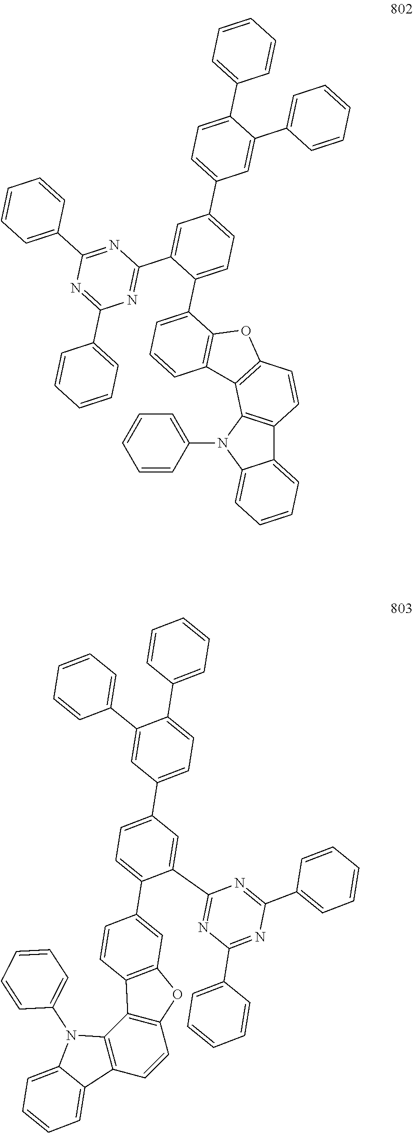 [SMILES: c1ccc(-c2nc(-c3ccccc3)nc(-c3cc(-c4ccc(-c5ccccc5)c(-c5ccccc5)c4)ccc3-c3cccc4c3oc3ccc5c6ccccc6n(-c6ccccc6)c5c34)n2)cc1 ; c1ccc(-c2nc(-c3ccccc3)nc(-c3cc(-c4ccc(-c5ccccc5)c(-c5ccccc5)c4)ccc3-c3ccc4c(c3)oc3ccc5c6ccccc6n(-c6ccccc6)c5c34)n2)cc1]

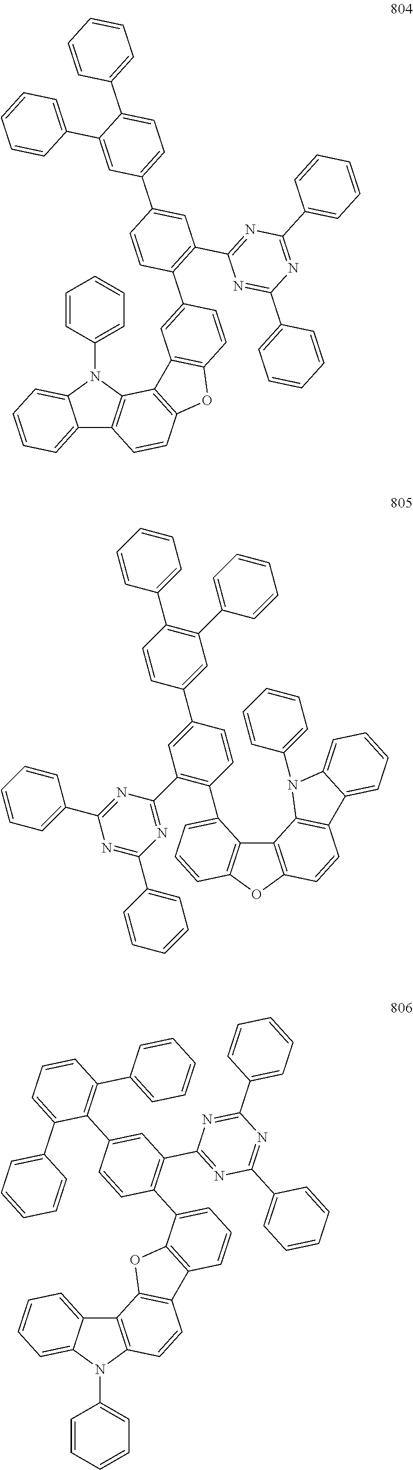 [SMILES: c1ccc(-c2nc(-c3ccccc3)nc(-c3cc(-c4ccc(-c5ccccc5)c(-c5ccccc5)c4)ccc3-c3ccc4oc5ccc6c7ccccc7n(-c7ccccc7)c6c5c4c3)n2)cc1 ; c1ccc(-c2nc(-c3ccccc3)nc(-c3cc(-c4ccc(-c5ccccc5)c(-c5ccccc5)c4)ccc3-c3cccc4oc5ccc6c7ccccc7n(-c7ccccc7)c6c5c34)n2)cc1 ; c1ccc(-c2nc(-c3ccccc3)nc(-c3cc(-c4c(-c5ccccc5)cccc4-c4ccccc4)ccc3-c3cccc4c3oc3c4ccc4c3c3ccccc3n4-c3ccccc3)n2)cc1]

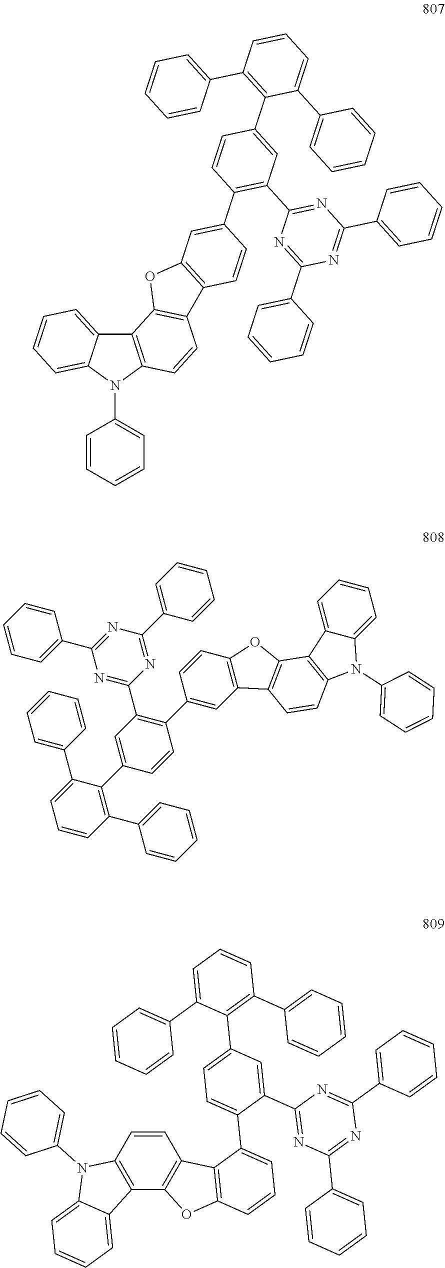 [SMILES: c1ccc(-c2nc(-c3ccccc3)nc(-c3cc(-c4c(-c5ccccc5)cccc4-c4ccccc4)ccc3-c3ccc4c(c3)oc3c4ccc4c3c3ccccc3n4-c3ccccc3)n2)cc1 ; c1ccc(-c2nc(-c3ccccc3)nc(-c3cc(-c4c(-c5ccccc5)cccc4-c4ccccc4)ccc3-c3ccc4oc5c(ccc6c5c5ccccc5n6-c5ccccc5)c4c3)n2)cc1 ; c1ccc(-c2nc(-c3ccccc3)nc(-c3cc(-c4c(-c5ccccc5)cccc4-c4ccccc4)ccc3-c3cccc4oc5c(ccc6c5c5ccccc5n6-c5ccccc5)c34)n2)cc1]

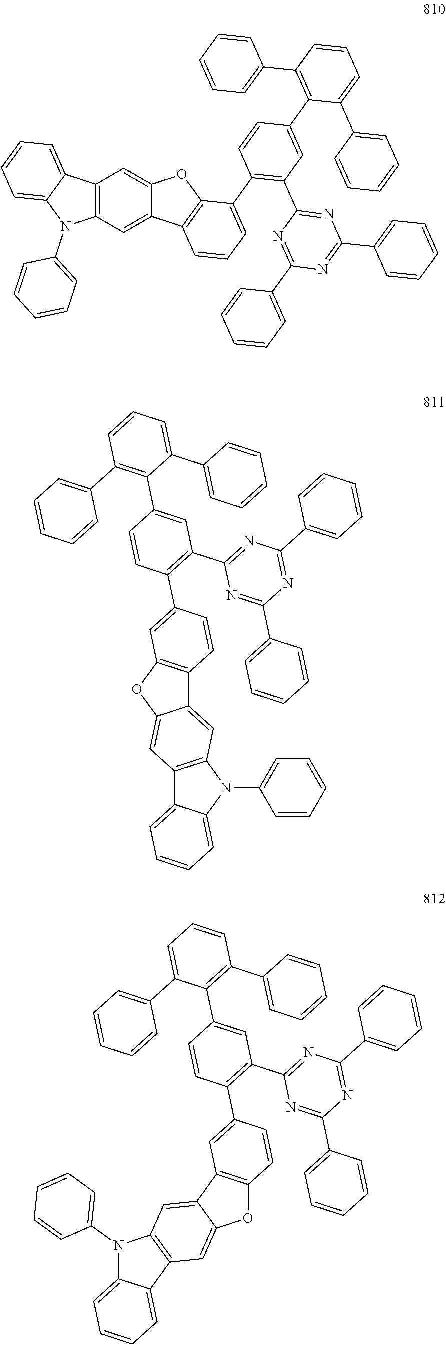 [SMILES: c1ccc(-c2nc(-c3ccccc3)nc(-c3cc(-c4c(-c5ccccc5)cccc4-c4ccccc4)ccc3-c3cccc4c3oc3cc5c6ccccc6n(-c6ccccc6)c5cc34)n2)cc1 ; c1ccc(-c2nc(-c3ccccc3)nc(-c3cc(-c4c(-c5ccccc5)cccc4-c4ccccc4)ccc3-c3ccc4c(c3)oc3cc5c6ccccc6n(-c6ccccc6)c5cc34)n2)cc1 ; c1ccc(-c2nc(-c3ccccc3)nc(-c3cc(-c4c(-c5ccccc5)cccc4-c4ccccc4)ccc3-c3ccc4oc5cc6c7ccccc7n(-c7ccccc7)c6cc5c4c3)n2)cc1]

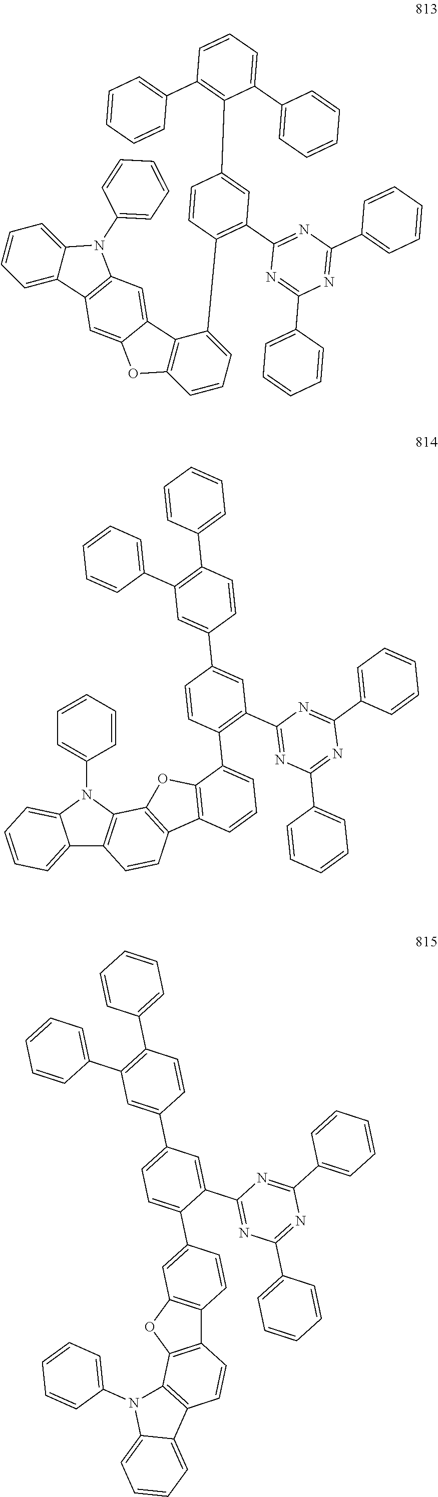 [SMILES: c1ccc(-c2nc(-c3ccccc3)nc(-c3cc(-c4c(-c5ccccc5)cccc4-c4ccccc4)ccc3-c3cccc4oc5cc6c7ccccc7n(-c7ccccc7)c6cc5c34)n2)cc1 ; c1ccc(-c2nc(-c3ccccc3)nc(-c3cc(-c4ccc(-c5ccccc5)c(-c5ccccc5)c4)ccc3-c3cccc4c3oc3c4ccc4c5ccccc5n(-c5ccccc5)c43)n2)cc1 ; c1ccc(-c2nc(-c3ccccc3)nc(-c3cc(-c4ccc(-c5ccccc5)c(-c5ccccc5)c4)ccc3-c3ccc4c(c3)oc3c4ccc4c5ccccc5n(-c5ccccc5)c43)n2)cc1]

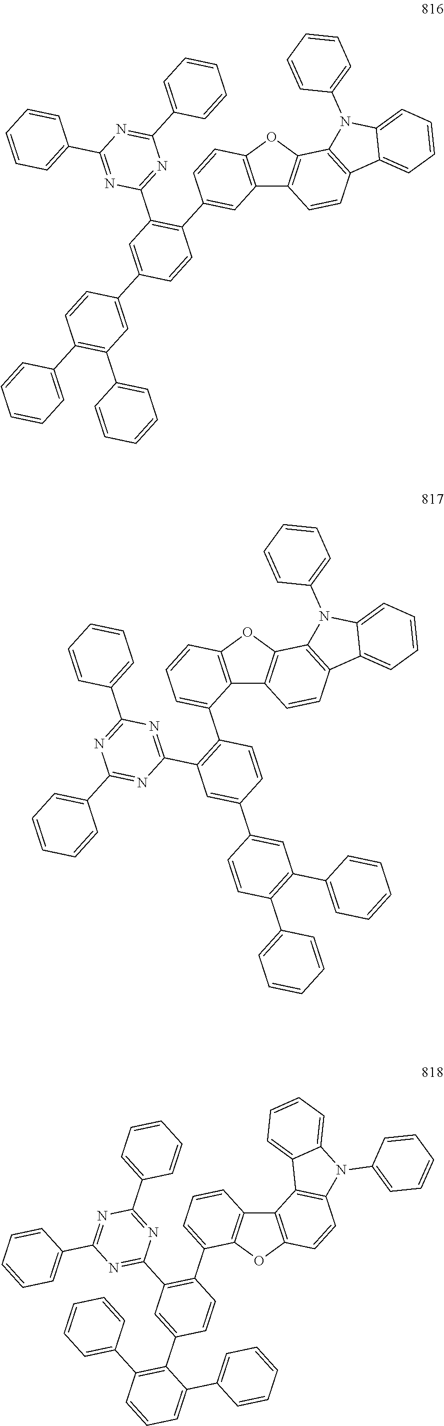 [SMILES: c1ccc(-c2nc(-c3ccccc3)nc(-c3cc(-c4ccc(-c5ccccc5)c(-c5ccccc5)c4)ccc3-c3ccc4oc5c(ccc6c7ccccc7n(-c7ccccc7)c65)c4c3)n2)cc1 ; c1ccc(-c2nc(-c3ccccc3)nc(-c3cc(-c4ccc(-c5ccccc5)c(-c5ccccc5)c4)ccc3-c3cccc4oc5c(ccc6c7ccccc7n(-c7ccccc7)c65)c34)n2)cc1 ; c1ccc(-c2nc(-c3ccccc3)nc(-c3cc(-c4c(-c5ccccc5)cccc4-c4ccccc4)ccc3-c3cccc4c3oc3ccc5c(c6ccccc6n5-c5ccccc5)c34)n2)cc1]

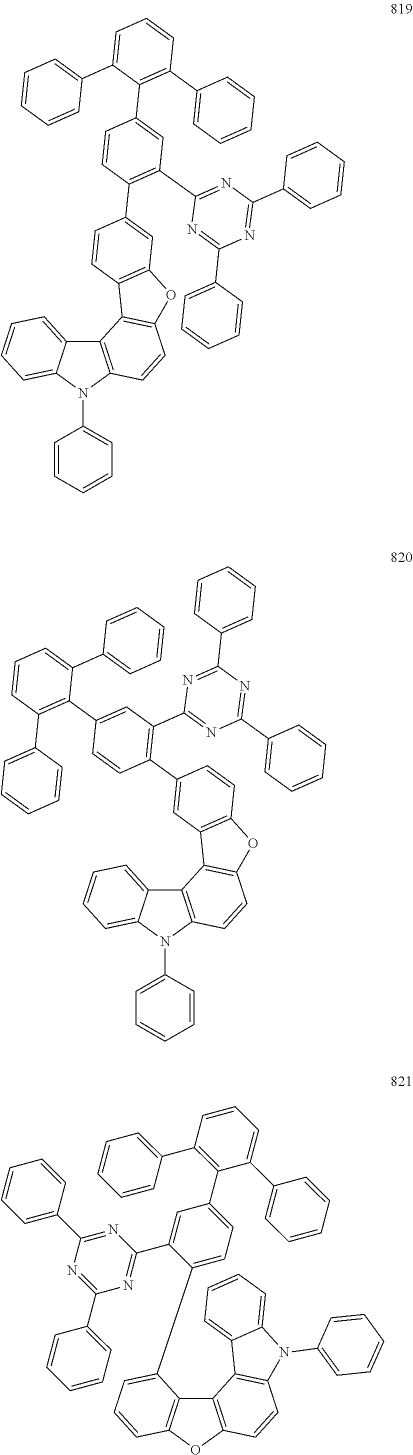 [SMILES: c1ccc(-c2nc(-c3ccccc3)nc(-c3cc(-c4c(-c5ccccc5)cccc4-c4ccccc4)ccc3-c3ccc4c(c3)oc3ccc5c(c6ccccc6n5-c5ccccc5)c34)n2)cc1 ; c1ccc(-c2nc(-c3ccccc3)nc(-c3cc(-c4c(-c5ccccc5)cccc4-c4ccccc4)ccc3-c3ccc4oc5ccc6c(c7ccccc7n6-c6ccccc6)c5c4c3)n2)cc1 ; c1ccc(-c2nc(-c3ccccc3)nc(-c3cc(-c4c(-c5ccccc5)cccc4-c4ccccc4)ccc3-c3cccc4oc5ccc6c(c7ccccc7n6-c6ccccc6)c5c34)n2)cc1]

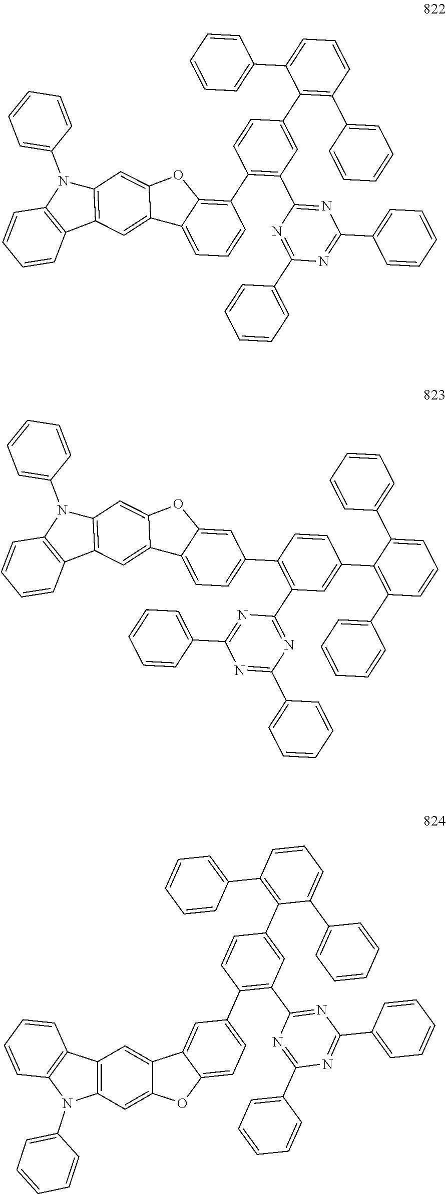 [SMILES: c1ccc(-c2nc(-c3ccccc3)nc(-c3cc(-c4c(-c5ccccc5)cccc4-c4ccccc4)ccc3-c3cccc4c3oc3cc5c(cc34)c3ccccc3n5-c3ccccc3)n2)cc1 ; c1ccc(-c2nc(-c3ccccc3)nc(-c3cc(-c4c(-c5ccccc5)cccc4-c4ccccc4)ccc3-c3ccc4c(c3)oc3cc5c(cc34)c3ccccc3n5-c3ccccc3)n2)cc1 ; c1ccc(-c2nc(-c3ccccc3)nc(-c3cc(-c4c(-c5ccccc5)cccc4-c4ccccc4)ccc3-c3ccc4oc5cc6c(cc5c4c3)c3ccccc3n6-c3ccccc3)n2)cc1]

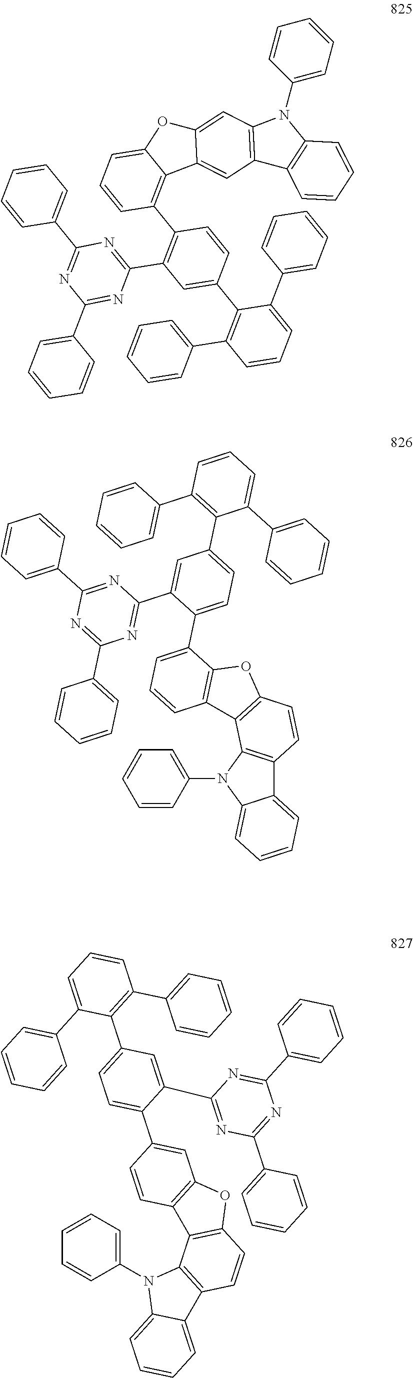 [SMILES: c1ccc(-c2nc(-c3ccccc3)nc(-c3cc(-c4c(-c5ccccc5)cccc4-c4ccccc4)ccc3-c3cccc4oc5cc6c(cc5c34)c3ccccc3n6-c3ccccc3)n2)cc1 ; c1ccc(-c2nc(-c3ccccc3)nc(-c3cc(-c4c(-c5ccccc5)cccc4-c4ccccc4)ccc3-c3cccc4c3oc3ccc5c6ccccc6n(-c6ccccc6)c5c34)n2)cc1 ; c1ccc(-c2nc(-c3ccccc3)nc(-c3cc(-c4c(-c5ccccc5)cccc4-c4ccccc4)ccc3-c3ccc4c(c3)oc3ccc5c6ccccc6n(-c6ccccc6)c5c34)n2)cc1]

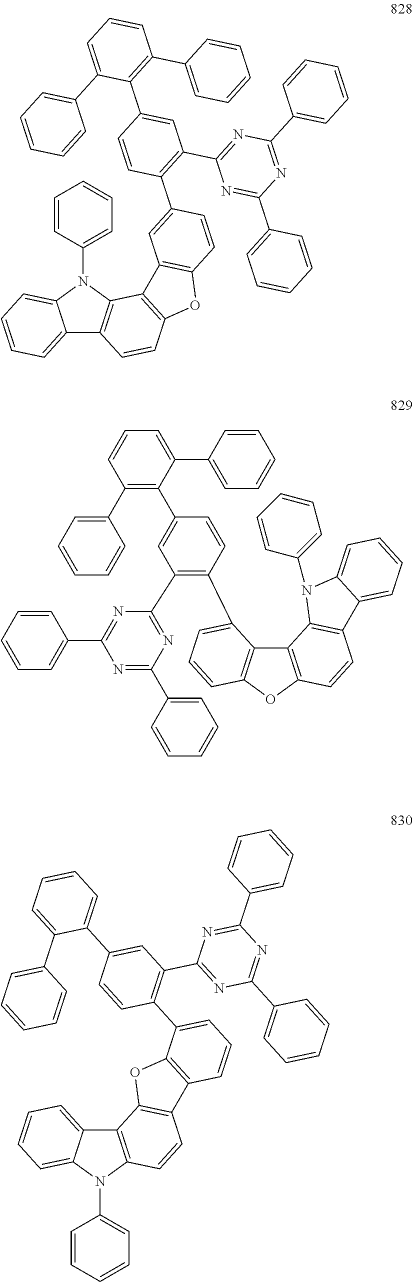 [SMILES: c1ccc(-c2nc(-c3ccccc3)nc(-c3cc(-c4c(-c5ccccc5)cccc4-c4ccccc4)ccc3-c3ccc4oc5ccc6c7ccccc7n(-c7ccccc7)c6c5c4c3)n2)cc1 ; c1ccc(-c2nc(-c3ccccc3)nc(-c3cc(-c4c(-c5ccccc5)cccc4-c4ccccc4)ccc3-c3cccc4oc5ccc6c7ccccc7n(-c7ccccc7)c6c5c34)n2)cc1 ; c1ccc(-c2nc(-c3ccccc3)nc(-c3cc(-c4ccccc4-c4ccccc4)ccc3-c3cccc4c3oc3c4ccc4c3c3ccccc3n4-c3ccccc3)n2)cc1]

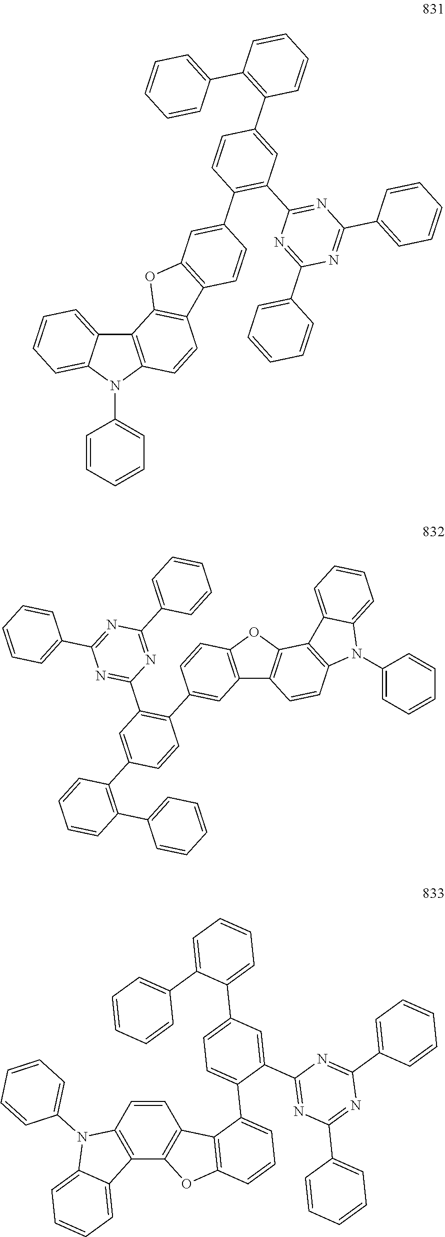 [SMILES: c1ccc(-c2nc(-c3ccccc3)nc(-c3cc(-c4ccccc4-c4ccccc4)ccc3-c3ccc4c(c3)oc3c4ccc4c3c3ccccc3n4-c3ccccc3)n2)cc1 ; c1ccc(-c2nc(-c3ccccc3)nc(-c3cc(-c4ccccc4-c4ccccc4)ccc3-c3ccc4oc5c(ccc6c5c5ccccc5n6-c5ccccc5)c4c3)n2)cc1 ; c1ccc(-c2nc(-c3ccccc3)nc(-c3cc(-c4ccccc4-c4ccccc4)ccc3-c3cccc4oc5c(ccc6c5c5ccccc5n6-c5ccccc5)c34)n2)cc1]

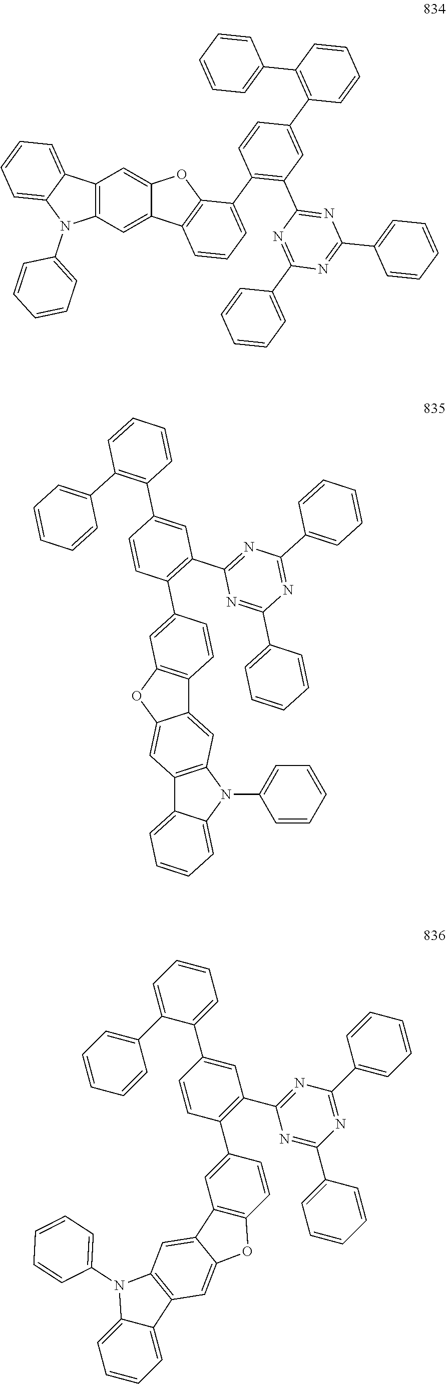 [SMILES: c1ccc(-c2nc(-c3ccccc3)nc(-c3cc(-c4ccccc4-c4ccccc4)ccc3-c3cccc4c3oc3cc5c6ccccc6n(-c6ccccc6)c5cc34)n2)cc1 ; c1ccc(-c2nc(-c3ccccc3)nc(-c3cc(-c4ccccc4-c4ccccc4)ccc3-c3ccc4c(c3)oc3cc5c6ccccc6n(-c6ccccc6)c5cc34)n2)cc1 ; c1ccc(-c2nc(-c3ccccc3)nc(-c3cc(-c4ccccc4-c4ccccc4)ccc3-c3ccc4oc5cc6c7ccccc7n(-c7ccccc7)c6cc5c4c3)n2)cc1]

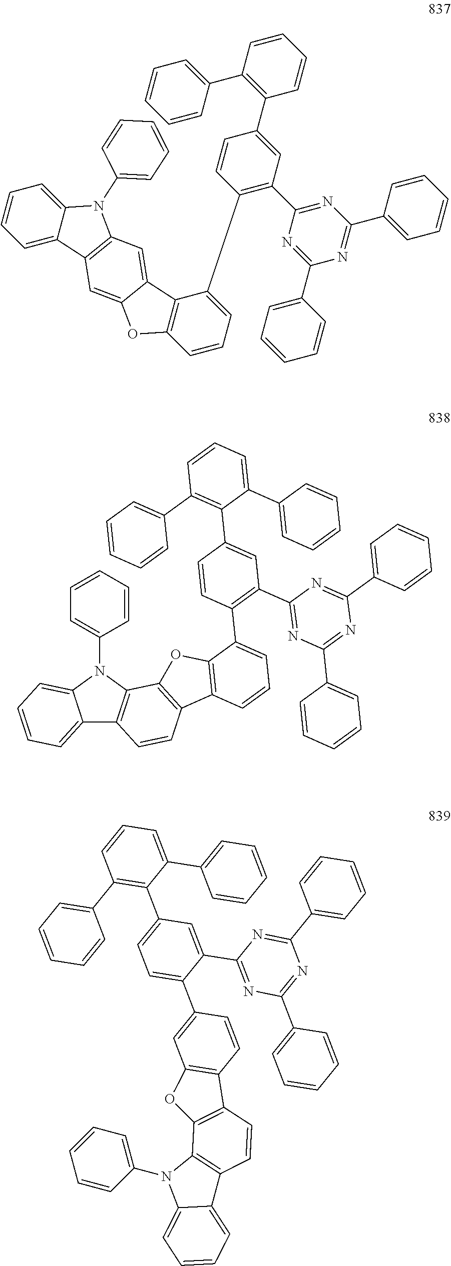 [SMILES: c1ccc(-c2nc(-c3ccccc3)nc(-c3cc(-c4ccccc4-c4ccccc4)ccc3-c3cccc4oc5cc6c7ccccc7n(-c7ccccc7)c6cc5c34)n2)cc1 ; c1ccc(-c2nc(-c3ccccc3)nc(-c3cc(-c4c(-c5ccccc5)cccc4-c4ccccc4)ccc3-c3cccc4c3oc3c4ccc4c5ccccc5n(-c5ccccc5)c43)n2)cc1 ; c1ccc(-c2nc(-c3ccccc3)nc(-c3cc(-c4c(-c5ccccc5)cccc4-c4ccccc4)ccc3-c3ccc4c(c3)oc3c4ccc4c5ccccc5n(-c5ccccc5)c43)n2)cc1]

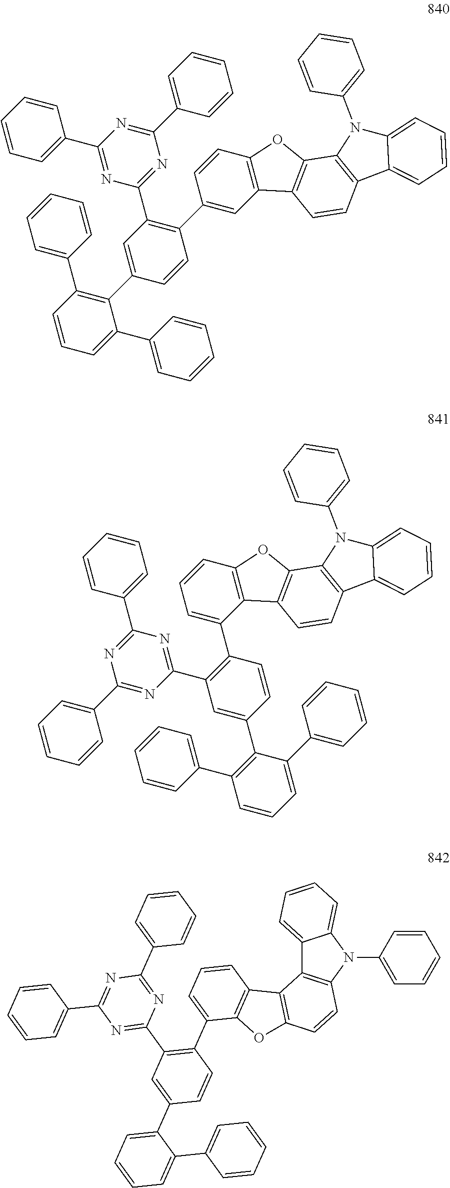 [SMILES: c1ccc(-c2nc(-c3ccccc3)nc(-c3cc(-c4c(-c5ccccc5)cccc4-c4ccccc4)ccc3-c3ccc4oc5c(ccc6c7ccccc7n(-c7ccccc7)c65)c4c3)n2)cc1 ; c1ccc(-c2nc(-c3ccccc3)nc(-c3cc(-c4c(-c5ccccc5)cccc4-c4ccccc4)ccc3-c3cccc4oc5c(ccc6c7ccccc7n(-c7ccccc7)c65)c34)n2)cc1 ; c1ccc(-c2nc(-c3ccccc3)nc(-c3cc(-c4ccccc4-c4ccccc4)ccc3-c3cccc4c3oc3ccc5c(c6ccccc6n5-c5ccccc5)c34)n2)cc1]

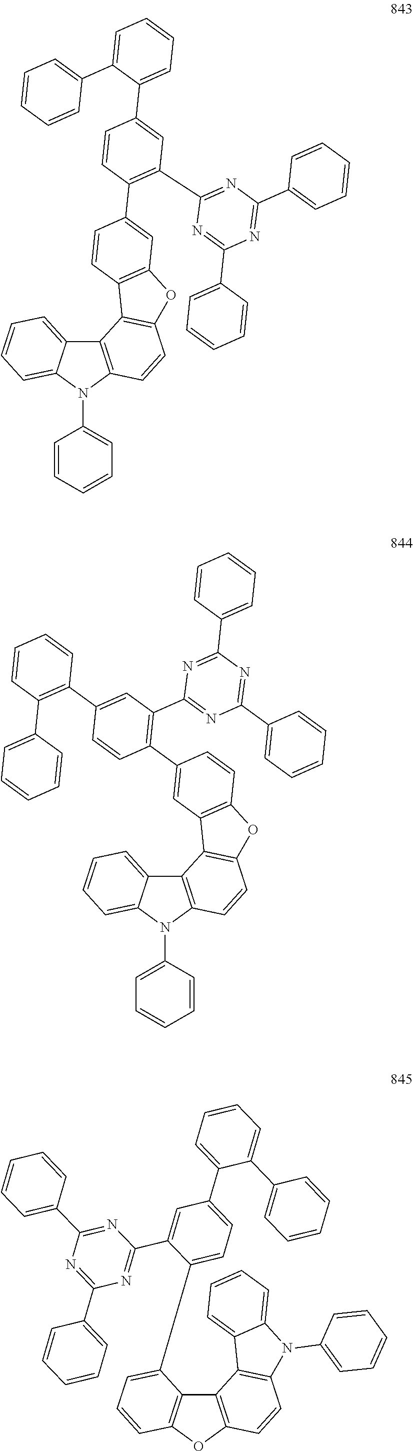 [SMILES: c1ccc(-c2nc(-c3ccccc3)nc(-c3cc(-c4ccccc4-c4ccccc4)ccc3-c3ccc4c(c3)oc3ccc5c(c6ccccc6n5-c5ccccc5)c34)n2)cc1 ; c1ccc(-c2nc(-c3ccccc3)nc(-c3cc(-c4ccccc4-c4ccccc4)ccc3-c3ccc4oc5ccc6c(c7ccccc7n6-c6ccccc6)c5c4c3)n2)cc1 ; c1ccc(-c2nc(-c3ccccc3)nc(-c3cc(-c4ccccc4-c4ccccc4)ccc3-c3cccc4oc5ccc6c(c7ccccc7n6-c6ccccc6)c5c34)n2)cc1]

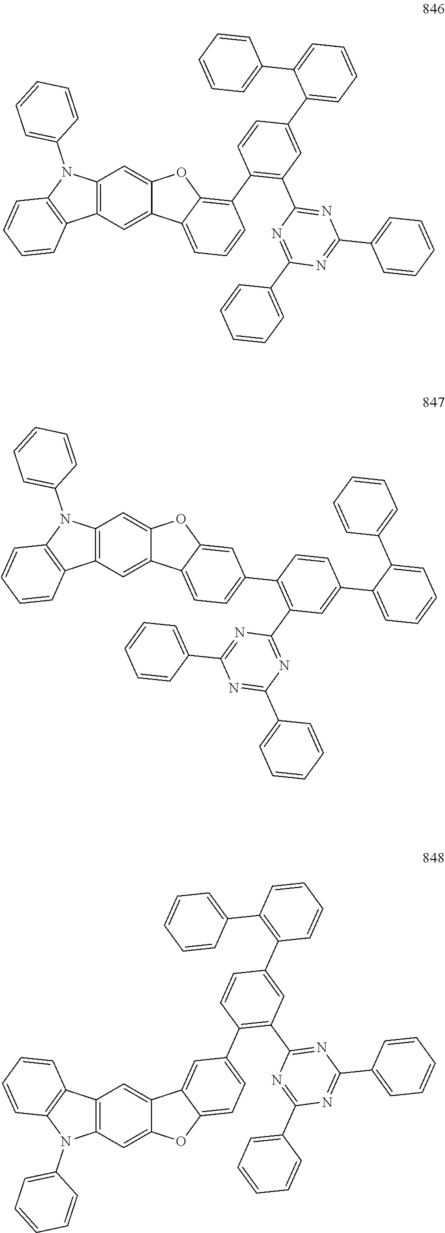 [SMILES: c1ccc(-c2nc(-c3ccccc3)nc(-c3cc(-c4ccccc4-c4ccccc4)ccc3-c3cccc4c3oc3cc5c(cc34)c3ccccc3n5-c3ccccc3)n2)cc1 ; c1ccc(-c2nc(-c3ccccc3)nc(-c3cc(-c4ccccc4-c4ccccc4)ccc3-c3ccc4c(c3)oc3cc5c(cc34)c3ccccc3n5-c3ccccc3)n2)cc1 ; c1ccc(-c2nc(-c3ccccc3)nc(-c3cc(-c4ccccc4-c4ccccc4)ccc3-c3ccc4oc5cc6c(cc5c4c3)c3ccccc3n6-c3ccccc3)n2)cc1]

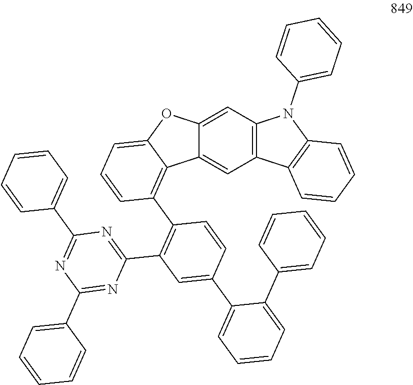 [SMILES: c1ccc(-c2nc(-c3ccccc3)nc(-c3cc(-c4ccccc4-c4ccccc4)ccc3-c3cccc4oc5cc6c(cc5c34)c3ccccc3n6-c3ccccc3)n2)cc1]

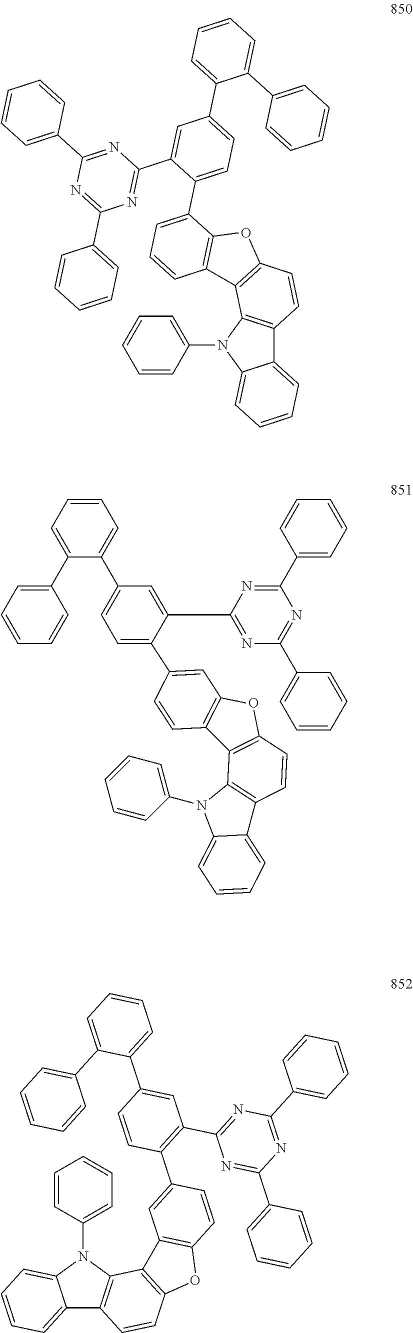 [SMILES: c1ccc(-c2nc(-c3ccccc3)nc(-c3cc(-c4ccccc4-c4ccccc4)ccc3-c3cccc4c3oc3ccc5c6ccccc6n(-c6ccccc6)c5c34)n2)cc1 ; c1ccc(-c2nc(-c3ccccc3)nc(-c3cc(-c4ccccc4-c4ccccc4)ccc3-c3ccc4c(c3)oc3ccc5c6ccccc6n(-c6ccccc6)c5c34)n2)cc1 ; c1ccc(-c2nc(-c3ccccc3)nc(-c3cc(-c4ccccc4-c4ccccc4)ccc3-c3ccc4oc5ccc6c7ccccc7n(-c7ccccc7)c6c5c4c3)n2)cc1]

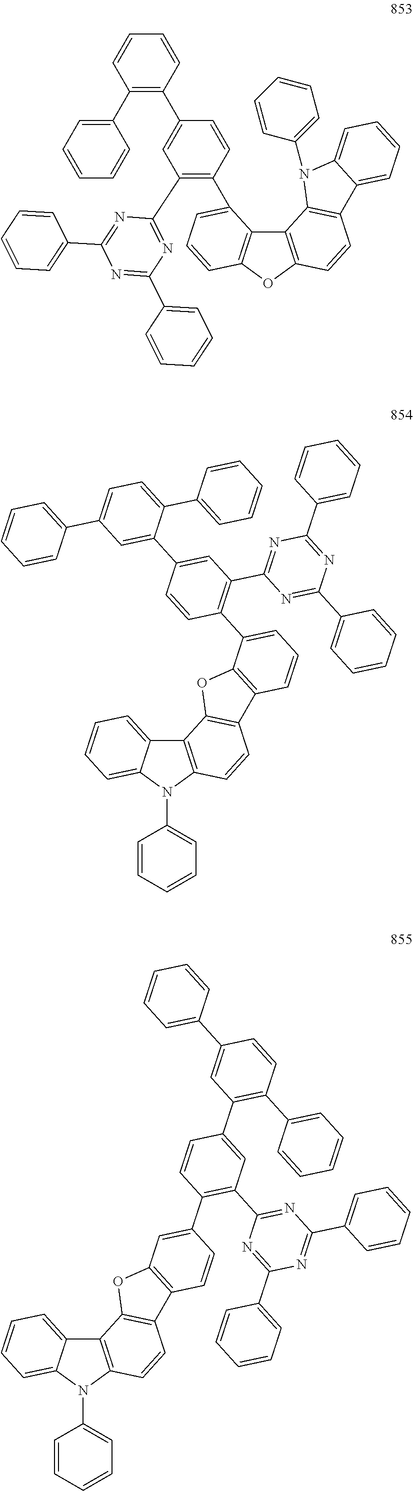 [SMILES: c1ccc(-c2nc(-c3ccccc3)nc(-c3cc(-c4ccccc4-c4ccccc4)ccc3-c3cccc4oc5ccc6c7ccccc7n(-c7ccccc7)c6c5c34)n2)cc1 ; c1ccc(-c2ccc(-c3ccccc3)c(-c3ccc(-c4cccc5c4oc4c5ccc5c4c4ccccc4n5-c4ccccc4)c(-c4nc(-c5ccccc5)nc(-c5ccccc5)n4)c3)c2)cc1 ; c1ccc(-c2ccc(-c3ccccc3)c(-c3ccc(-c4ccc5c(c4)oc4c5ccc5c4c4ccccc4n5-c4ccccc4)c(-c4nc(-c5ccccc5)nc(-c5ccccc5)n4)c3)c2)cc1]

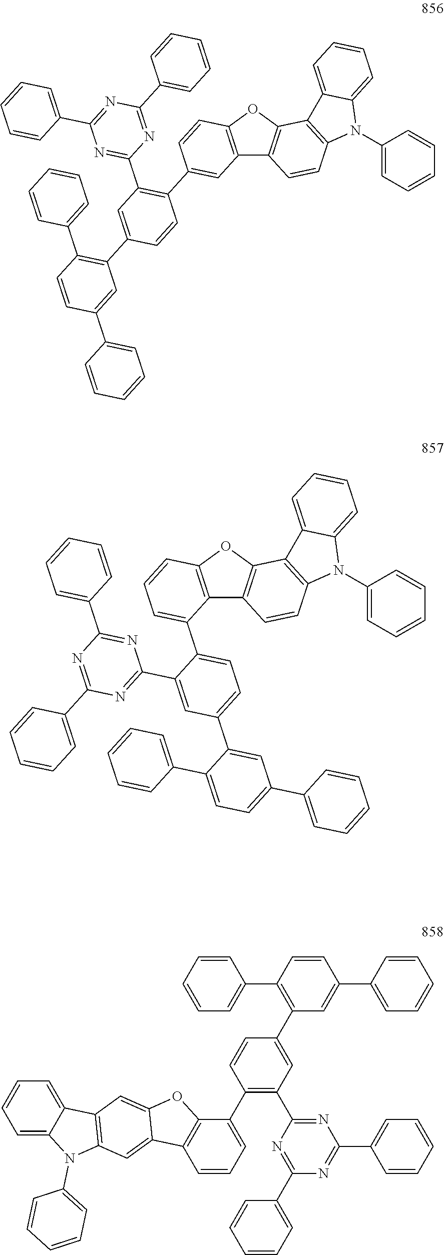 [SMILES: c1ccc(-c2ccc(-c3ccccc3)c(-c3ccc(-c4ccc5oc6c(ccc7c6c6ccccc6n7-c6ccccc6)c5c4)c(-c4nc(-c5ccccc5)nc(-c5ccccc5)n4)c3)c2)cc1 ; c1ccc(-c2ccc(-c3ccccc3)c(-c3ccc(-c4cccc5oc6c(ccc7c6c6ccccc6n7-c6ccccc6)c45)c(-c4nc(-c5ccccc5)nc(-c5ccccc5)n4)c3)c2)cc1 ; c1ccc(-c2ccc(-c3ccccc3)c(-c3ccc(-c4cccc5c4oc4cc6c7ccccc7n(-c7ccccc7)c6cc45)c(-c4nc(-c5ccccc5)nc(-c5ccccc5)n4)c3)c2)cc1]

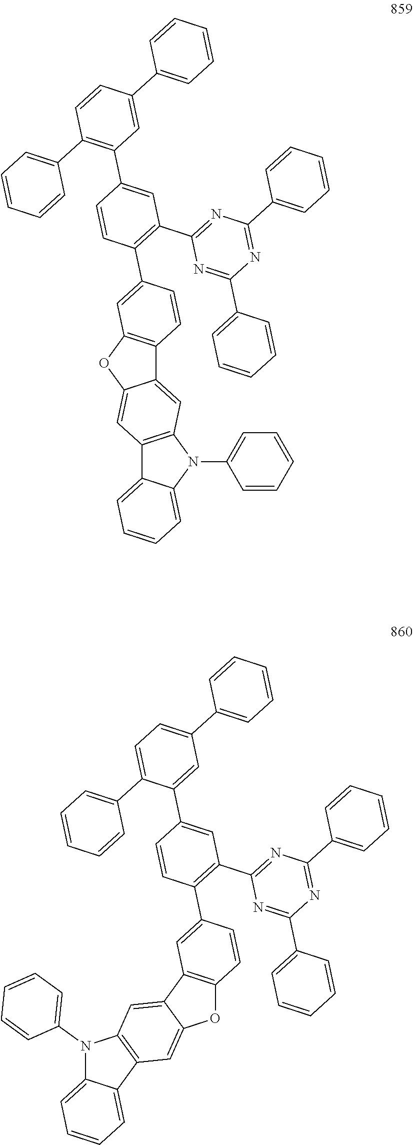 [SMILES: c1ccc(-c2ccc(-c3ccccc3)c(-c3ccc(-c4ccc5c(c4)oc4cc6c7ccccc7n(-c7ccccc7)c6cc45)c(-c4nc(-c5ccccc5)nc(-c5ccccc5)n4)c3)c2)cc1 ; c1ccc(-c2ccc(-c3ccccc3)c(-c3ccc(-c4ccc5oc6cc7c8ccccc8n(-c8ccccc8)c7cc6c5c4)c(-c4nc(-c5ccccc5)nc(-c5ccccc5)n4)c3)c2)cc1]

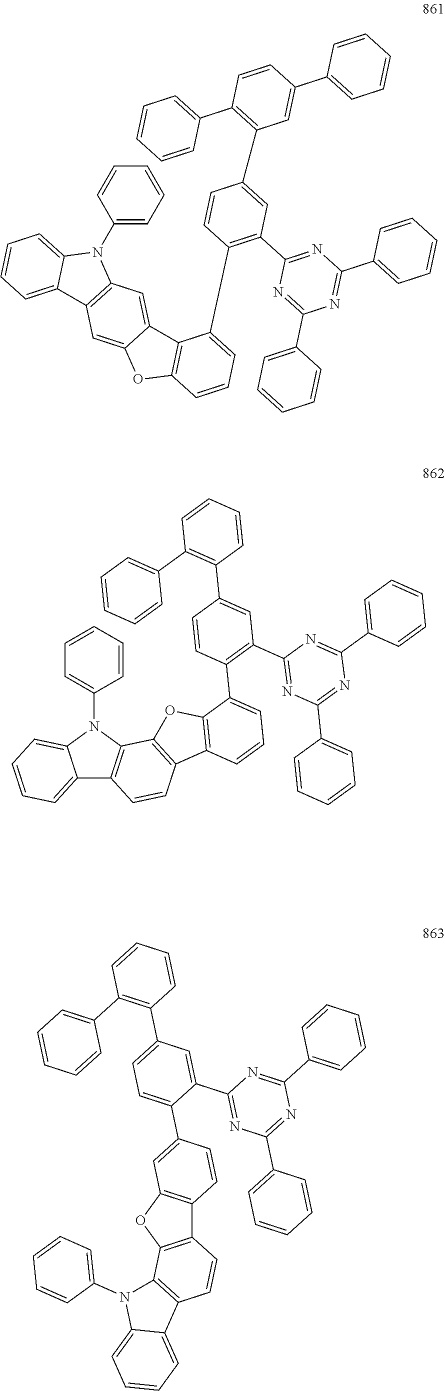 [SMILES: c1ccc(-c2ccc(-c3ccccc3)c(-c3ccc(-c4cccc5oc6cc7c8ccccc8n(-c8ccccc8)c7cc6c45)c(-c4nc(-c5ccccc5)nc(-c5ccccc5)n4)c3)c2)cc1 ; c1ccc(-c2nc(-c3ccccc3)nc(-c3cc(-c4ccccc4-c4ccccc4)ccc3-c3cccc4c3oc3c4ccc4c5ccccc5n(-c5ccccc5)c43)n2)cc1 ; c1ccc(-c2nc(-c3ccccc3)nc(-c3cc(-c4ccccc4-c4ccccc4)ccc3-c3ccc4c(c3)oc3c4ccc4c5ccccc5n(-c5ccccc5)c43)n2)cc1]

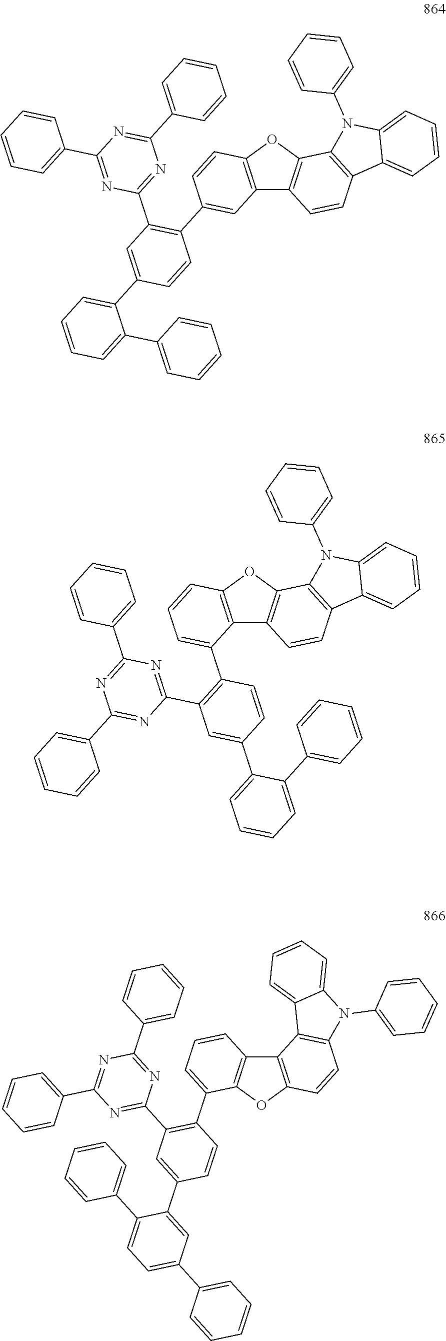 [SMILES: c1ccc(-c2nc(-c3ccccc3)nc(-c3cc(-c4ccccc4-c4ccccc4)ccc3-c3ccc4oc5c(ccc6c7ccccc7n(-c7ccccc7)c65)c4c3)n2)cc1 ; c1ccc(-c2nc(-c3ccccc3)nc(-c3cc(-c4ccccc4-c4ccccc4)ccc3-c3cccc4oc5c(ccc6c7ccccc7n(-c7ccccc7)c65)c34)n2)cc1 ; c1ccc(-c2ccc(-c3ccccc3)c(-c3ccc(-c4cccc5c4oc4ccc6c(c7ccccc7n6-c6ccccc6)c45)c(-c4nc(-c5ccccc5)nc(-c5ccccc5)n4)c3)c2)cc1]

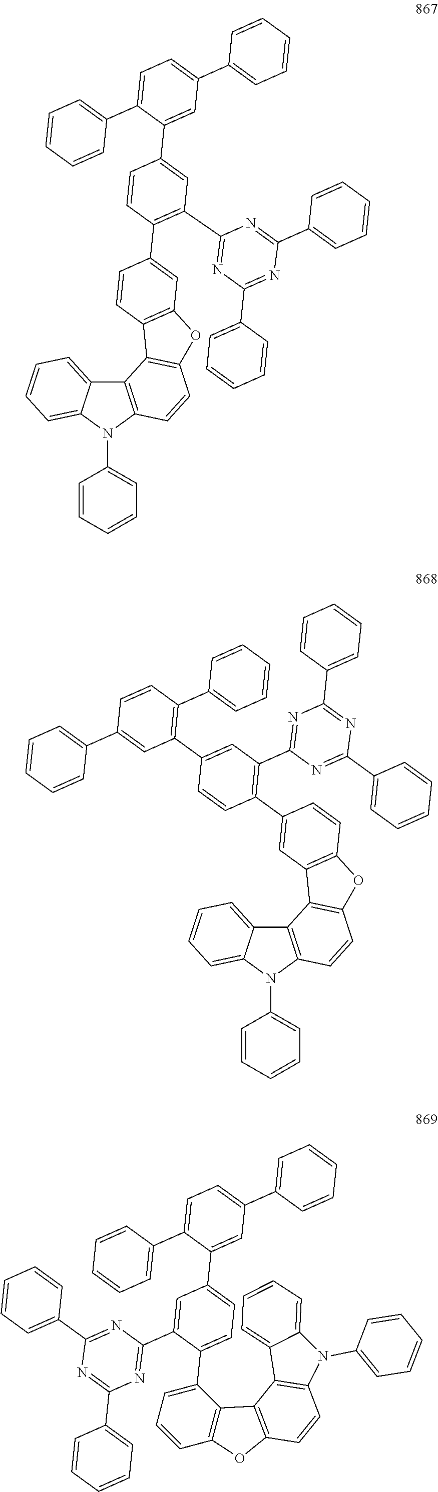 [SMILES: c1ccc(-c2ccc(-c3ccccc3)c(-c3ccc(-c4ccc5c(c4)oc4ccc6c(c7ccccc7n6-c6ccccc6)c45)c(-c4nc(-c5ccccc5)nc(-c5ccccc5)n4)c3)c2)cc1 ; c1ccc(-c2ccc(-c3ccccc3)c(-c3ccc(-c4ccc5oc6ccc7c(c8ccccc8n7-c7ccccc7)c6c5c4)c(-c4nc(-c5ccccc5)nc(-c5ccccc5)n4)c3)c2)cc1 ; c1ccc(-c2ccc(-c3ccccc3)c(-c3ccc(-c4cccc5oc6ccc7c(c8ccccc8n7-c7ccccc7)c6c45)c(-c4nc(-c5ccccc5)nc(-c5ccccc5)n4)c3)c2)cc1]

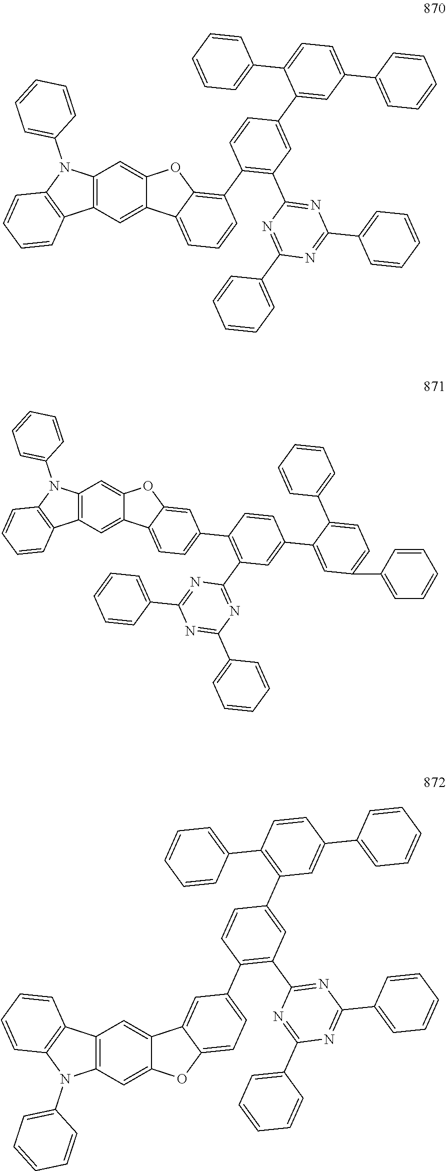 [SMILES: c1ccc(-c2ccc(-c3ccccc3)c(-c3ccc(-c4cccc5c4oc4cc6c(cc45)c4ccccc4n6-c4ccccc4)c(-c4nc(-c5ccccc5)nc(-c5ccccc5)n4)c3)c2)cc1 ; c1ccc(-c2ccc(-c3ccccc3)c(-c3ccc(-c4ccc5c(c4)oc4cc6c(cc45)c4ccccc4n6-c4ccccc4)c(-c4nc(-c5ccccc5)nc(-c5ccccc5)n4)c3)c2)cc1 ; c1ccc(-c2ccc(-c3ccccc3)c(-c3ccc(-c4ccc5oc6cc7c(cc6c5c4)c4ccccc4n7-c4ccccc4)c(-c4nc(-c5ccccc5)nc(-c5ccccc5)n4)c3)c2)cc1]

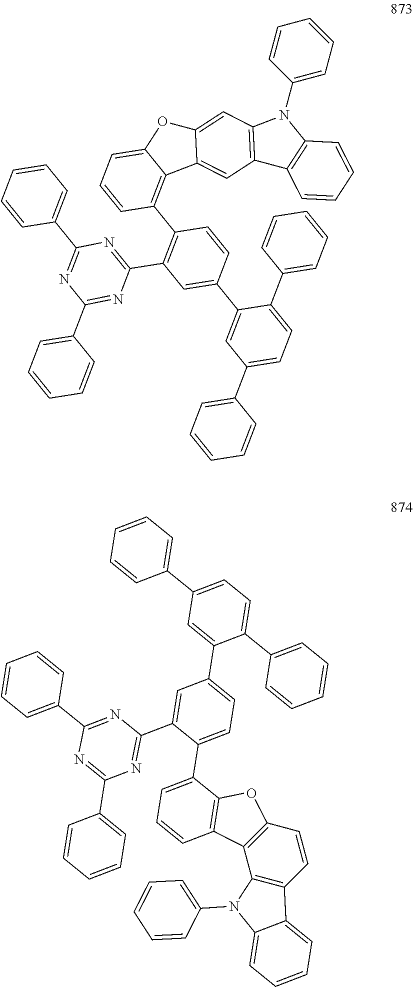 [SMILES: c1ccc(-c2ccc(-c3ccccc3)c(-c3ccc(-c4cccc5oc6cc7c(cc6c45)c4ccccc4n7-c4ccccc4)c(-c4nc(-c5ccccc5)nc(-c5ccccc5)n4)c3)c2)cc1 ; c1ccc(-c2ccc(-c3ccccc3)c(-c3ccc(-c4cccc5c4oc4ccc6c7ccccc7n(-c7ccccc7)c6c45)c(-c4nc(-c5ccccc5)nc(-c5ccccc5)n4)c3)c2)cc1]

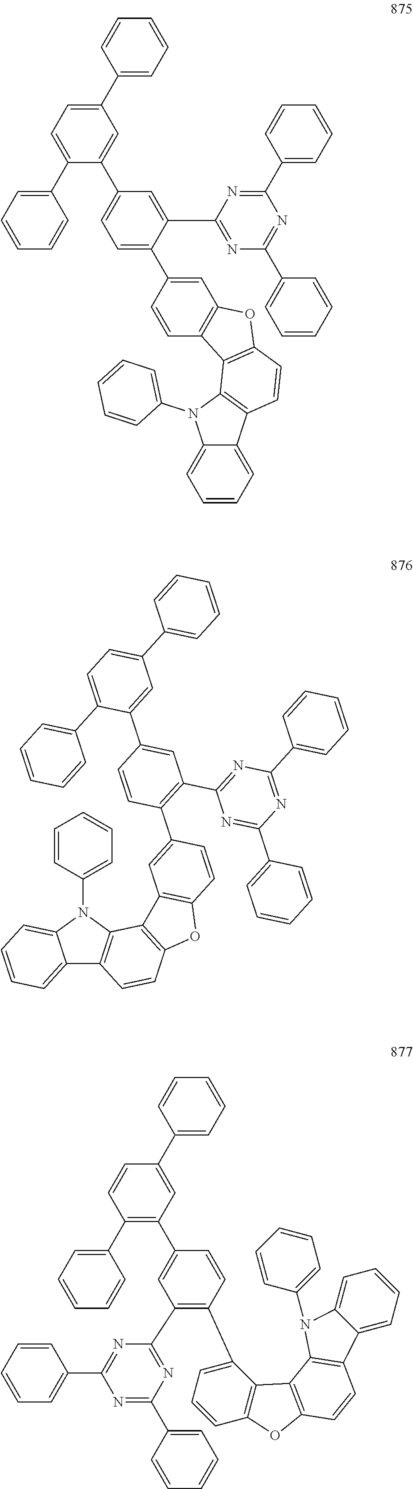 [SMILES: c1ccc(-c2ccc(-c3ccccc3)c(-c3ccc(-c4ccc5c(c4)oc4ccc6c7ccccc7n(-c7ccccc7)c6c45)c(-c4nc(-c5ccccc5)nc(-c5ccccc5)n4)c3)c2)cc1 ; c1ccc(-c2ccc(-c3ccccc3)c(-c3ccc(-c4ccc5oc6ccc7c8ccccc8n(-c8ccccc8)c7c6c5c4)c(-c4nc(-c5ccccc5)nc(-c5ccccc5)n4)c3)c2)cc1 ; c1ccc(-c2ccc(-c3ccccc3)c(-c3ccc(-c4cccc5oc6ccc7c8ccccc8n(-c8ccccc8)c7c6c45)c(-c4nc(-c5ccccc5)nc(-c5ccccc5)n4)c3)c2)cc1]

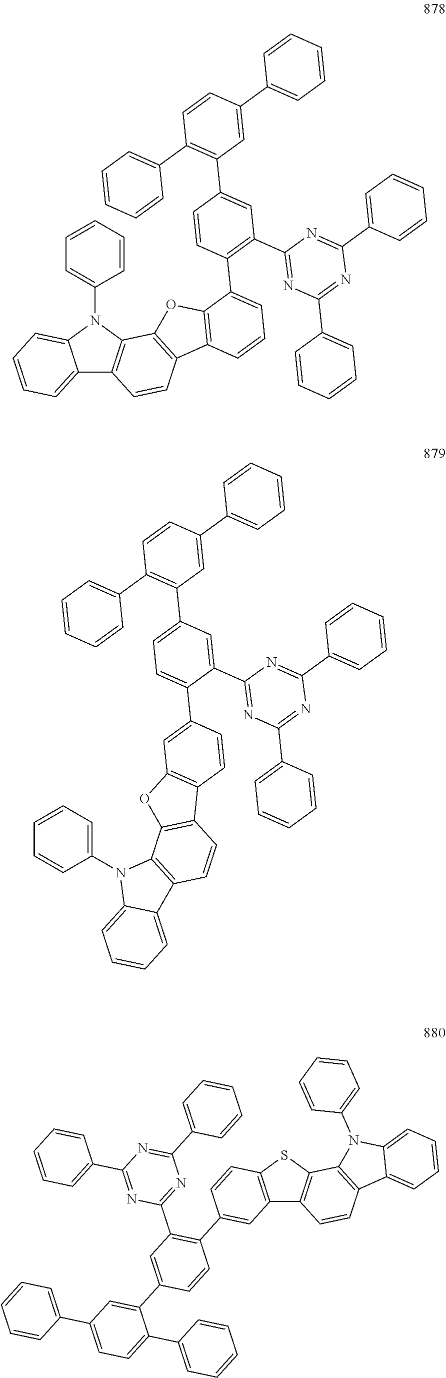 [SMILES: c1ccc(-c2ccc(-c3ccccc3)c(-c3ccc(-c4cccc5c4oc4c5ccc5c6ccccc6n(-c6ccccc6)c54)c(-c4nc(-c5ccccc5)nc(-c5ccccc5)n4)c3)c2)cc1 ; c1ccc(-c2ccc(-c3ccccc3)c(-c3ccc(-c4ccc5c(c4)oc4c5ccc5c6ccccc6n(-c6ccccc6)c54)c(-c4nc(-c5ccccc5)nc(-c5ccccc5)n4)c3)c2)cc1 ; c1ccc(-c2ccc(-c3ccccc3)c(-c3ccc(-c4ccc5sc6c(ccc7c8ccccc8n(-c8ccccc8)c76)c5c4)c(-c4nc(-c5ccccc5)nc(-c5ccccc5)n4)c3)c2)cc1]

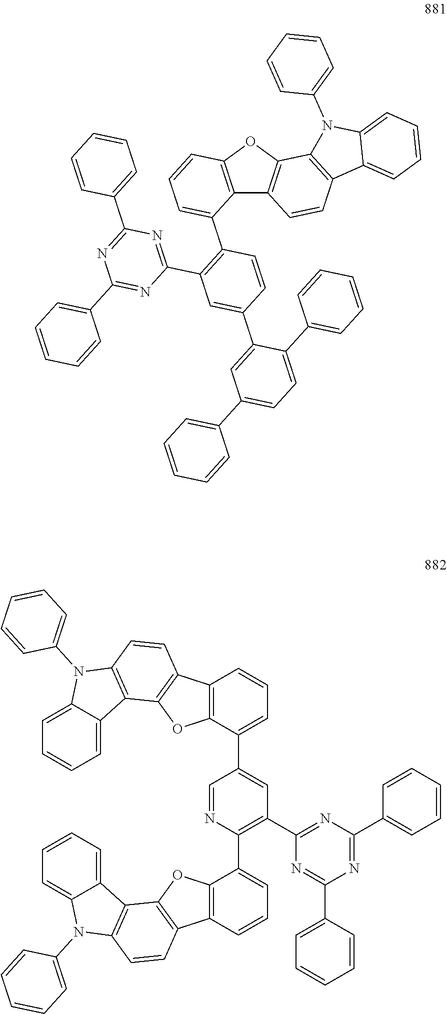 [SMILES: c1ccc(-c2ccc(-c3ccccc3)c(-c3ccc(-c4cccc5oc6c(ccc7c8ccccc8n(-c8ccccc8)c76)c45)c(-c4nc(-c5ccccc5)nc(-c5ccccc5)n4)c3)c2)cc1 ; c1ccc(-c2nc(-c3ccccc3)nc(-c3cc(-c4cccc5c4oc4c5ccc5c4c4ccccc4n5-c4ccccc4)cnc3-c3cccc4c3oc3c4ccc4c3c3ccccc3n4-c3ccccc3)n2)cc1]

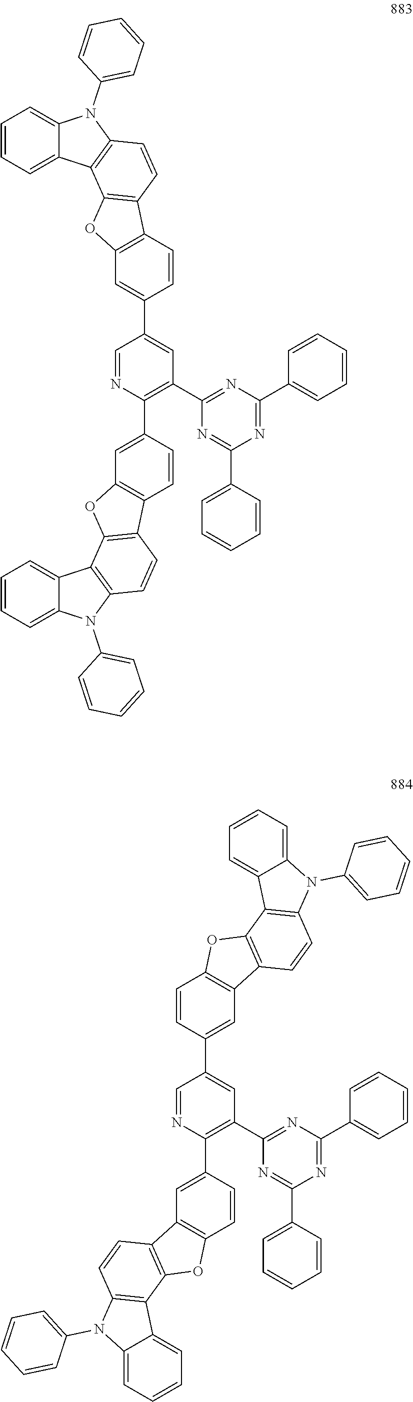 [SMILES: c1ccc(-c2nc(-c3ccccc3)nc(-c3cc(-c4ccc5c(c4)oc4c5ccc5c4c4ccccc4n5-c4ccccc4)cnc3-c3ccc4c(c3)oc3c4ccc4c3c3ccccc3n4-c3ccccc3)n2)cc1 ; c1ccc(-c2nc(-c3ccccc3)nc(-c3cc(-c4ccc5oc6c(ccc7c6c6ccccc6n7-c6ccccc6)c5c4)cnc3-c3ccc4oc5c(ccc6c5c5ccccc5n6-c5ccccc5)c4c3)n2)cc1]

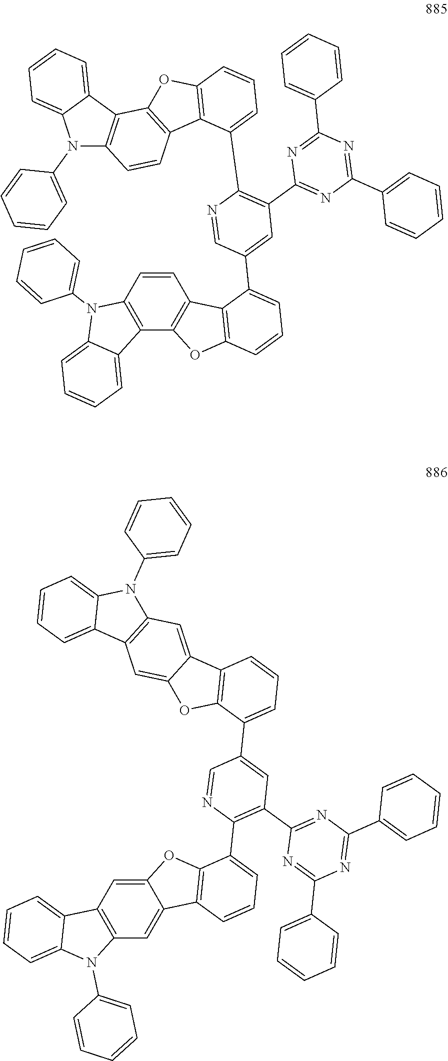 [SMILES: c1ccc(-c2nc(-c3ccccc3)nc(-c3cc(-c4cccc5oc6c(ccc7c6c6ccccc6n7-c6ccccc6)c45)cnc3-c3cccc4oc5c(ccc6c5c5ccccc5n6-c5ccccc5)c34)n2)cc1 ; c1ccc(-c2nc(-c3ccccc3)nc(-c3cc(-c4cccc5c4oc4cc6c7ccccc7n(-c7ccccc7)c6cc45)cnc3-c3cccc4c3oc3cc5c6ccccc6n(-c6ccccc6)c5cc34)n2)cc1]

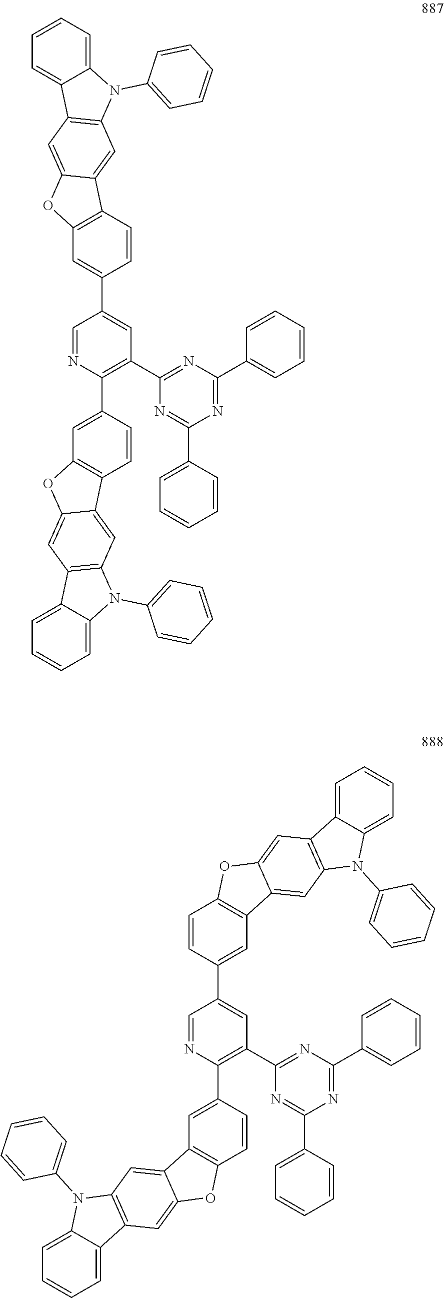 [SMILES: c1ccc(-c2nc(-c3ccccc3)nc(-c3cc(-c4ccc5c(c4)oc4cc6c7ccccc7n(-c7ccccc7)c6cc45)cnc3-c3ccc4c(c3)oc3cc5c6ccccc6n(-c6ccccc6)c5cc34)n2)cc1 ; c1ccc(-c2nc(-c3ccccc3)nc(-c3cc(-c4ccc5oc6cc7c8ccccc8n(-c8ccccc8)c7cc6c5c4)cnc3-c3ccc4oc5cc6c7ccccc7n(-c7ccccc7)c6cc5c4c3)n2)cc1]

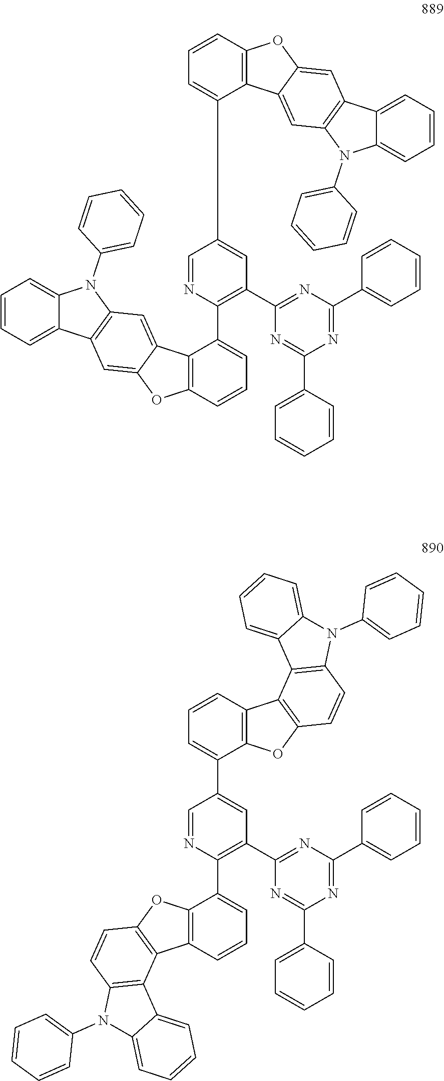 [SMILES: c1ccc(-c2nc(-c3ccccc3)nc(-c3cc(-c4cccc5oc6cc7c8ccccc8n(-c8ccccc8)c7cc6c45)cnc3-c3cccc4oc5cc6c7ccccc7n(-c7ccccc7)c6cc5c34)n2)cc1 ; c1ccc(-c2nc(-c3ccccc3)nc(-c3cc(-c4cccc5c4oc4ccc6c(c7ccccc7n6-c6ccccc6)c45)cnc3-c3cccc4c3oc3ccc5c(c6ccccc6n5-c5ccccc5)c34)n2)cc1]

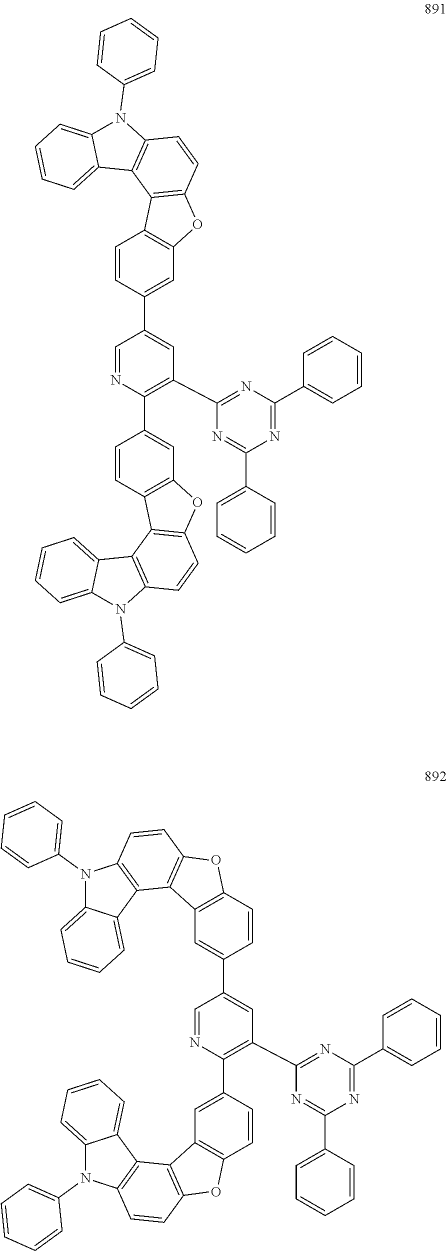 [SMILES: c1ccc(-c2nc(-c3ccccc3)nc(-c3cc(-c4ccc5c(c4)oc4ccc6c(c7ccccc7n6-c6ccccc6)c45)cnc3-c3ccc4c(c3)oc3ccc5c(c6ccccc6n5-c5ccccc5)c34)n2)cc1 ; c1ccc(-c2nc(-c3ccccc3)nc(-c3cc(-c4ccc5oc6ccc7c(c8ccccc8n7-c7ccccc7)c6c5c4)cnc3-c3ccc4oc5ccc6c(c7ccccc7n6-c6ccccc6)c5c4c3)n2)cc1]

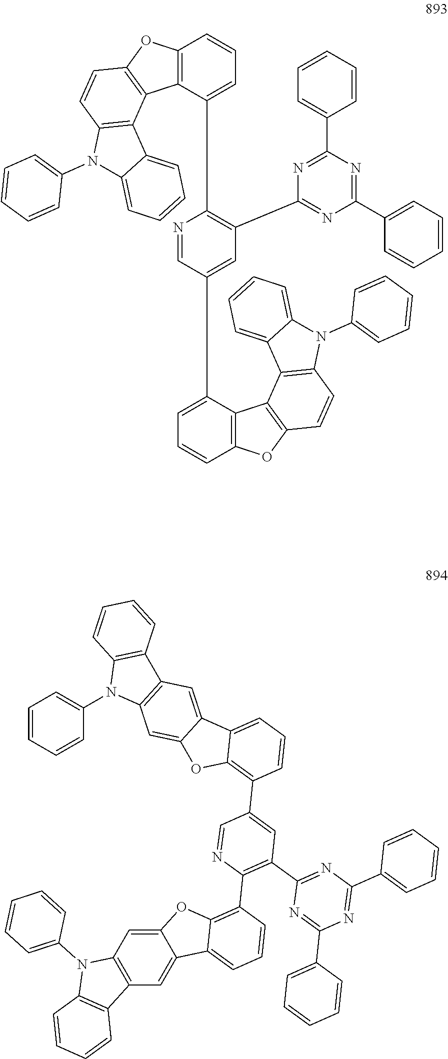 [SMILES: c1ccc(-c2nc(-c3ccccc3)nc(-c3cc(-c4cccc5oc6ccc7c(c8ccccc8n7-c7ccccc7)c6c45)cnc3-c3cccc4oc5ccc6c(c7ccccc7n6-c6ccccc6)c5c34)n2)cc1 ; c1ccc(-c2nc(-c3ccccc3)nc(-c3cc(-c4cccc5c4oc4cc6c(cc45)c4ccccc4n6-c4ccccc4)cnc3-c3cccc4c3oc3cc5c(cc34)c3ccccc3n5-c3ccccc3)n2)cc1]

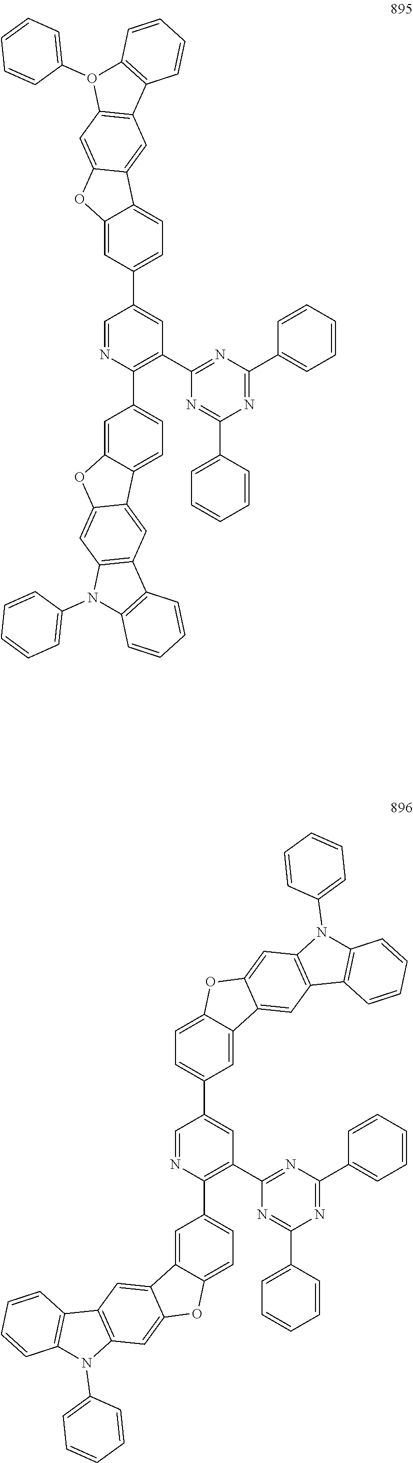

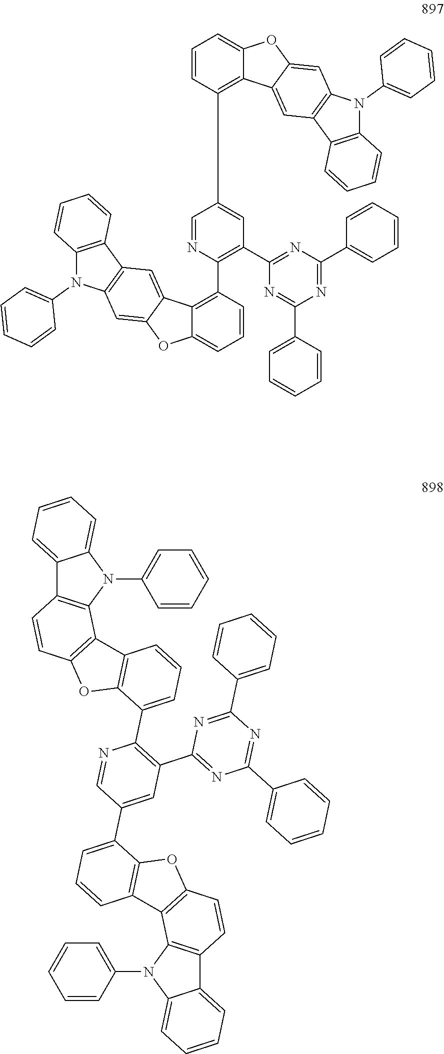 [SMILES: c1ccc(-c2nc(-c3ccccc3)nc(-c3cc(-c4cccc5oc6cc7c(cc6c45)c4ccccc4n7-c4ccccc4)cnc3-c3cccc4oc5cc6c(cc5c34)c3ccccc3n6-c3ccccc3)n2)cc1 ; c1ccc(-c2nc(-c3ccccc3)nc(-c3cc(-c4cccc5c4oc4ccc6c7ccccc7n(-c7ccccc7)c6c45)cnc3-c3cccc4c3oc3ccc5c6ccccc6n(-c6ccccc6)c5c34)n2)cc1]

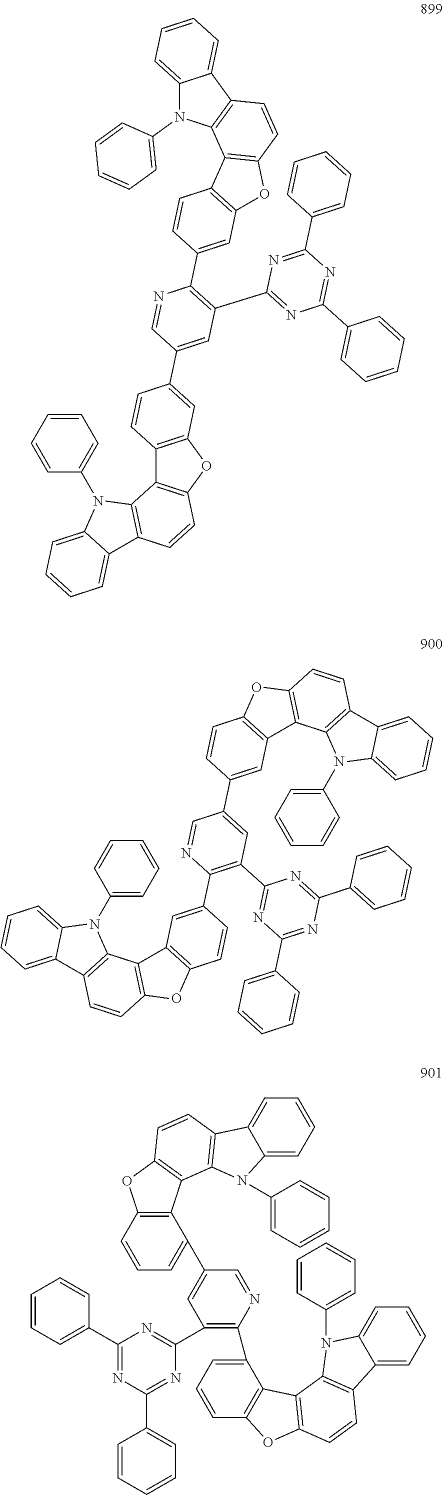 [SMILES: c1ccc(-c2nc(-c3ccccc3)nc(-c3cc(-c4ccc5c(c4)oc4ccc6c7ccccc7n(-c7ccccc7)c6c45)cnc3-c3ccc4c(c3)oc3ccc5c6ccccc6n(-c6ccccc6)c5c34)n2)cc1 ; c1ccc(-c2nc(-c3ccccc3)nc(-c3cc(-c4ccc5oc6ccc7c8ccccc8n(-c8ccccc8)c7c6c5c4)cnc3-c3ccc4oc5ccc6c7ccccc7n(-c7ccccc7)c6c5c4c3)n2)cc1 ; c1ccc(-c2nc(-c3ccccc3)nc(-c3cc(-c4cccc5oc6ccc7c8ccccc8n(-c8ccccc8)c7c6c45)cnc3-c3cccc4oc5ccc6c7ccccc7n(-c7ccccc7)c6c5c34)n2)cc1]

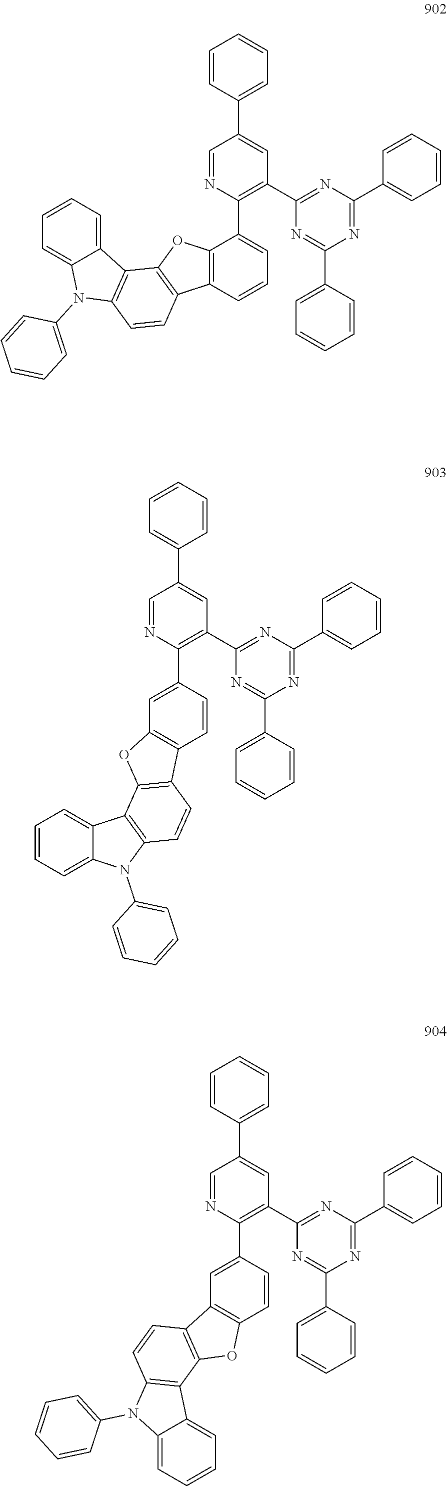 [SMILES: c1ccc(-c2cnc(-c3cccc4c3oc3c4ccc4c3c3ccccc3n4-c3ccccc3)c(-c3nc(-c4ccccc4)nc(-c4ccccc4)n3)c2)cc1 ; c1ccc(-c2cnc(-c3ccc4c(c3)oc3c4ccc4c3c3ccccc3n4-c3ccccc3)c(-c3nc(-c4ccccc4)nc(-c4ccccc4)n3)c2)cc1 ; c1ccc(-c2cnc(-c3ccc4oc5c(ccc6c5c5ccccc5n6-c5ccccc5)c4c3)c(-c3nc(-c4ccccc4)nc(-c4ccccc4)n3)c2)cc1]

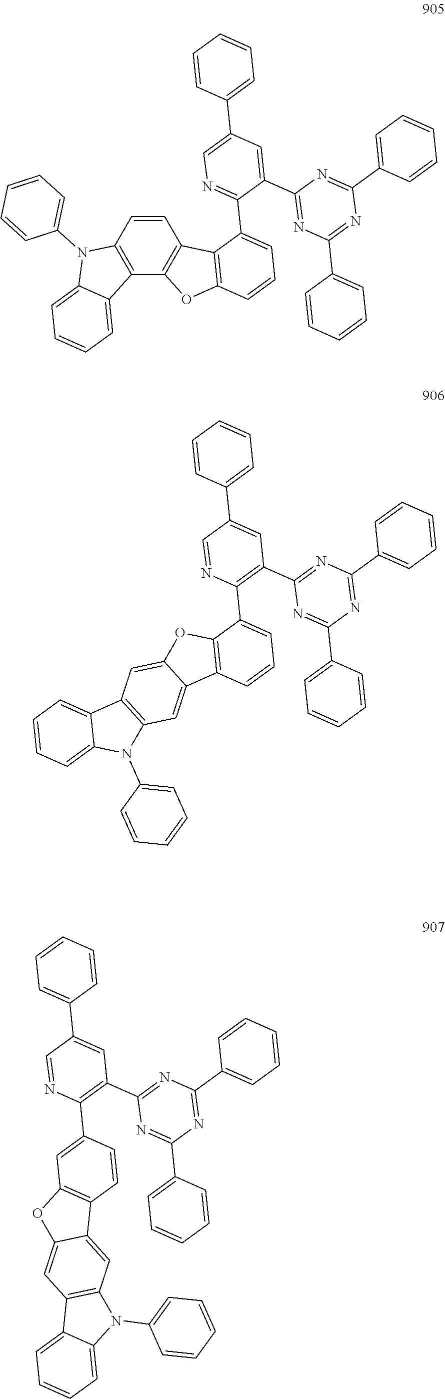 [SMILES: c1ccc(-c2cnc(-c3cccc4oc5c(ccc6c5c5ccccc5n6-c5ccccc5)c34)c(-c3nc(-c4ccccc4)nc(-c4ccccc4)n3)c2)cc1 ; c1ccc(-c2cnc(-c3cccc4c3oc3cc5c6ccccc6n(-c6ccccc6)c5cc34)c(-c3nc(-c4ccccc4)nc(-c4ccccc4)n3)c2)cc1 ; c1ccc(-c2cnc(-c3ccc4c(c3)oc3cc5c6ccccc6n(-c6ccccc6)c5cc34)c(-c3nc(-c4ccccc4)nc(-c4ccccc4)n3)c2)cc1]

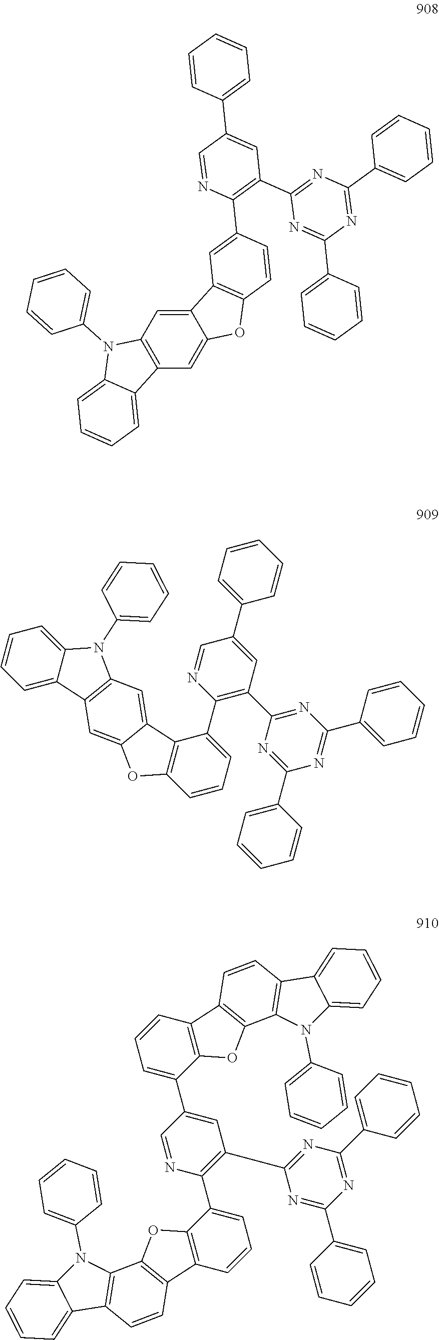 [SMILES: c1ccc(-c2cnc(-c3ccc4oc5cc6c7ccccc7n(-c7ccccc7)c6cc5c4c3)c(-c3nc(-c4ccccc4)nc(-c4ccccc4)n3)c2)cc1 ; c1ccc(-c2cnc(-c3cccc4oc5cc6c7ccccc7n(-c7ccccc7)c6cc5c34)c(-c3nc(-c4ccccc4)nc(-c4ccccc4)n3)c2)cc1 ; c1ccc(-c2nc(-c3ccccc3)nc(-c3cc(-c4cccc5c4oc4c5ccc5c6ccccc6n(-c6ccccc6)c54)cnc3-c3cccc4c3oc3c4ccc4c5ccccc5n(-c5ccccc5)c43)n2)cc1]

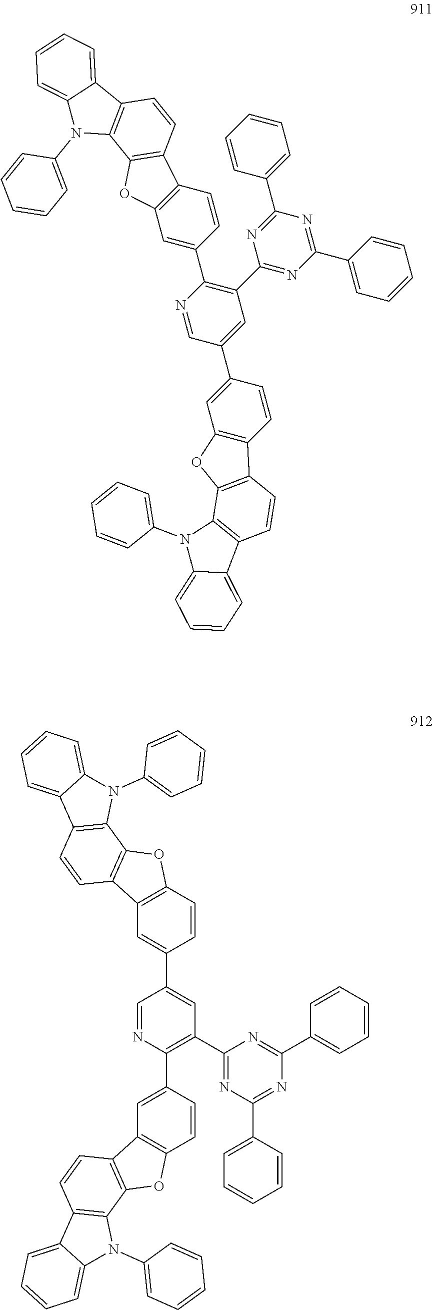 [SMILES: c1ccc(-c2nc(-c3ccccc3)nc(-c3cc(-c4ccc5c(c4)oc4c5ccc5c6ccccc6n(-c6ccccc6)c54)cnc3-c3ccc4c(c3)oc3c4ccc4c5ccccc5n(-c5ccccc5)c43)n2)cc1 ; c1ccc(-c2nc(-c3ccccc3)nc(-c3cc(-c4ccc5oc6c(ccc7c8ccccc8n(-c8ccccc8)c76)c5c4)cnc3-c3ccc4oc5c(ccc6c7ccccc7n(-c7ccccc7)c65)c4c3)n2)cc1]

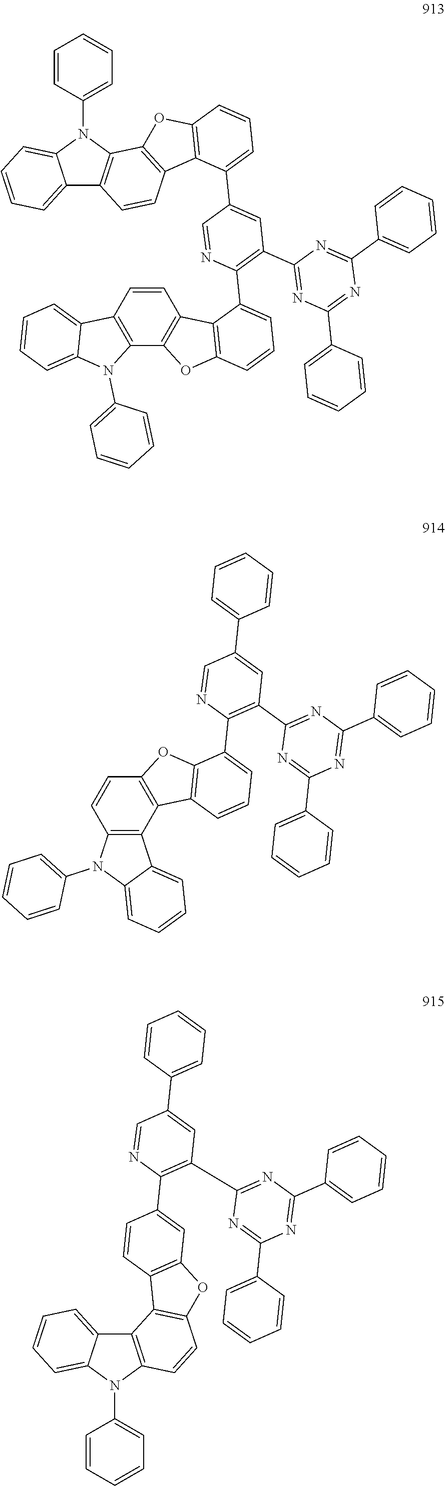 [SMILES: c1ccc(-c2nc(-c3ccccc3)nc(-c3cc(-c4cccc5oc6c(ccc7c8ccccc8n(-c8ccccc8)c76)c45)cnc3-c3cccc4oc5c(ccc6c7ccccc7n(-c7ccccc7)c65)c34)n2)cc1 ; c1ccc(-c2cnc(-c3cccc4c3oc3ccc5c(c6ccccc6n5-c5ccccc5)c34)c(-c3nc(-c4ccccc4)nc(-c4ccccc4)n3)c2)cc1 ; c1ccc(-c2cnc(-c3ccc4c(c3)oc3ccc5c(c6ccccc6n5-c5ccccc5)c34)c(-c3nc(-c4ccccc4)nc(-c4ccccc4)n3)c2)cc1]

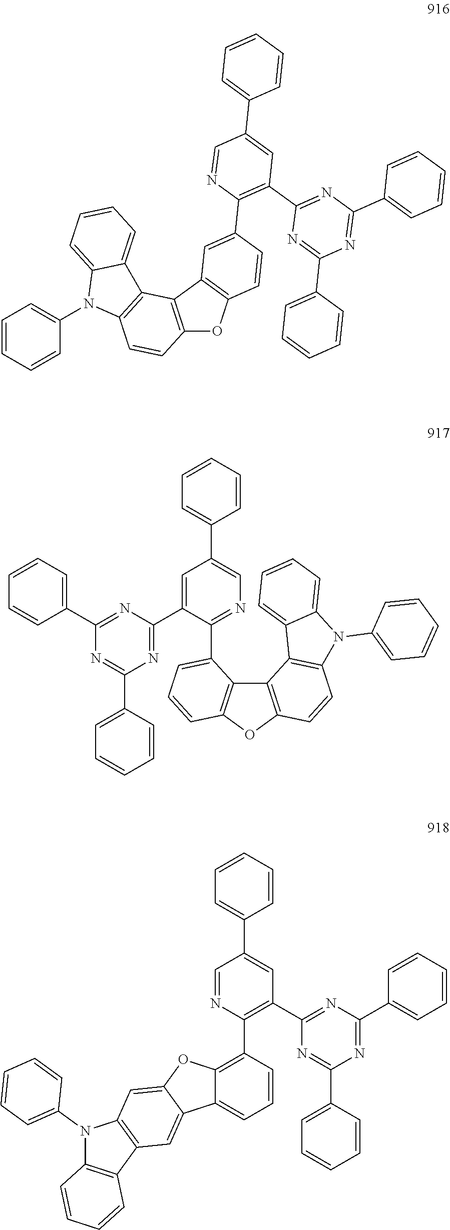 [SMILES: c1ccc(-c2cnc(-c3ccc4oc5ccc6c(c7ccccc7n6-c6ccccc6)c5c4c3)c(-c3nc(-c4ccccc4)nc(-c4ccccc4)n3)c2)cc1 ; c1ccc(-c2cnc(-c3cccc4oc5ccc6c(c7ccccc7n6-c6ccccc6)c5c34)c(-c3nc(-c4ccccc4)nc(-c4ccccc4)n3)c2)cc1 ; c1ccc(-c2cnc(-c3cccc4c3oc3cc5c(cc34)c3ccccc3n5-c3ccccc3)c(-c3nc(-c4ccccc4)nc(-c4ccccc4)n3)c2)cc1]

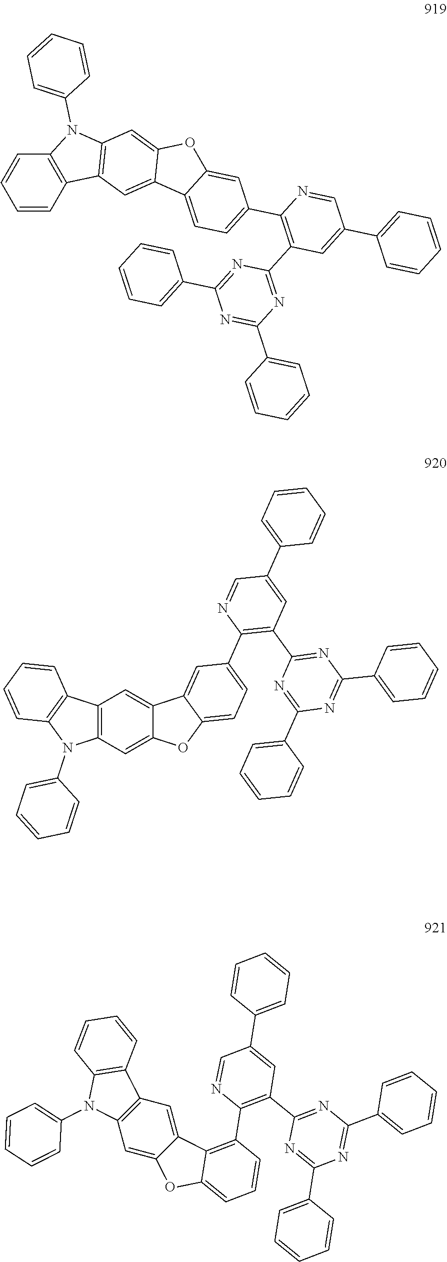 [SMILES: c1ccc(-c2cnc(-c3ccc4c(c3)oc3cc5c(cc34)c3ccccc3n5-c3ccccc3)c(-c3nc(-c4ccccc4)nc(-c4ccccc4)n3)c2)cc1 ; c1ccc(-c2cnc(-c3ccc4oc5cc6c(cc5c4c3)c3ccccc3n6-c3ccccc3)c(-c3nc(-c4ccccc4)nc(-c4ccccc4)n3)c2)cc1 ; c1ccc(-c2cnc(-c3cccc4oc5cc6c(cc5c34)c3ccccc3n6-c3ccccc3)c(-c3nc(-c4ccccc4)nc(-c4ccccc4)n3)c2)cc1]

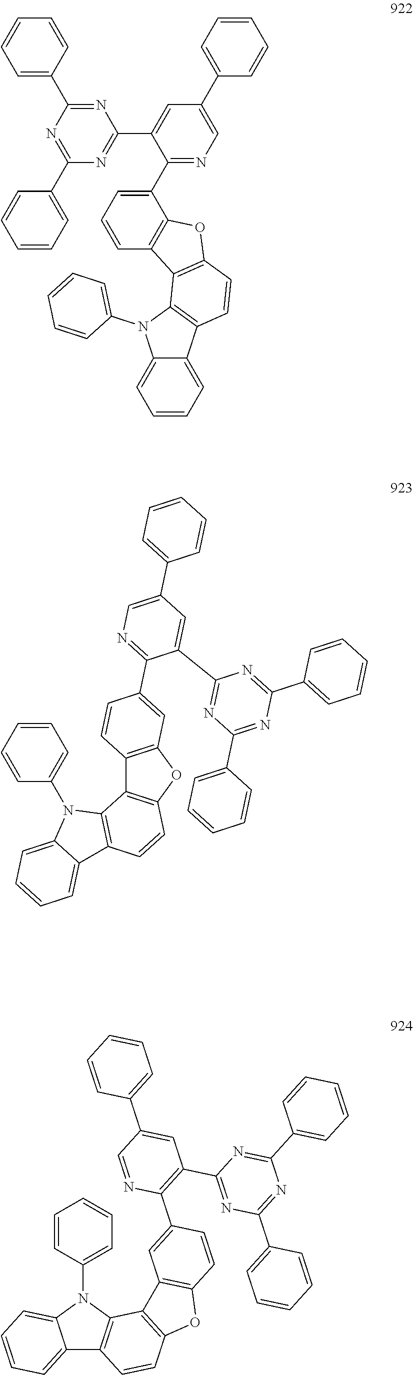 [SMILES: c1ccc(-c2cnc(-c3cccc4c3oc3ccc5c6ccccc6n(-c6ccccc6)c5c34)c(-c3nc(-c4ccccc4)nc(-c4ccccc4)n3)c2)cc1 ; c1ccc(-c2cnc(-c3ccc4c(c3)oc3ccc5c6ccccc6n(-c6ccccc6)c5c34)c(-c3nc(-c4ccccc4)nc(-c4ccccc4)n3)c2)cc1 ; c1ccc(-c2cnc(-c3ccc4oc5ccc6c7ccccc7n(-c7ccccc7)c6c5c4c3)c(-c3nc(-c4ccccc4)nc(-c4ccccc4)n3)c2)cc1]

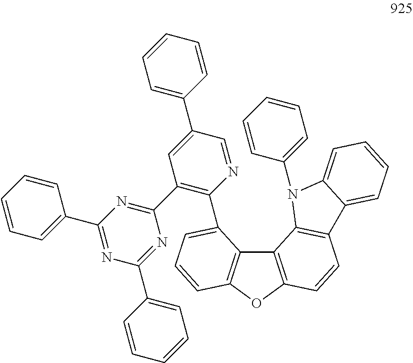 [SMILES: c1ccc(-c2cnc(-c3cccc4oc5ccc6c7ccccc7n(-c7ccccc7)c6c5c34)c(-c3nc(-c4ccccc4)nc(-c4ccccc4)n3)c2)cc1]

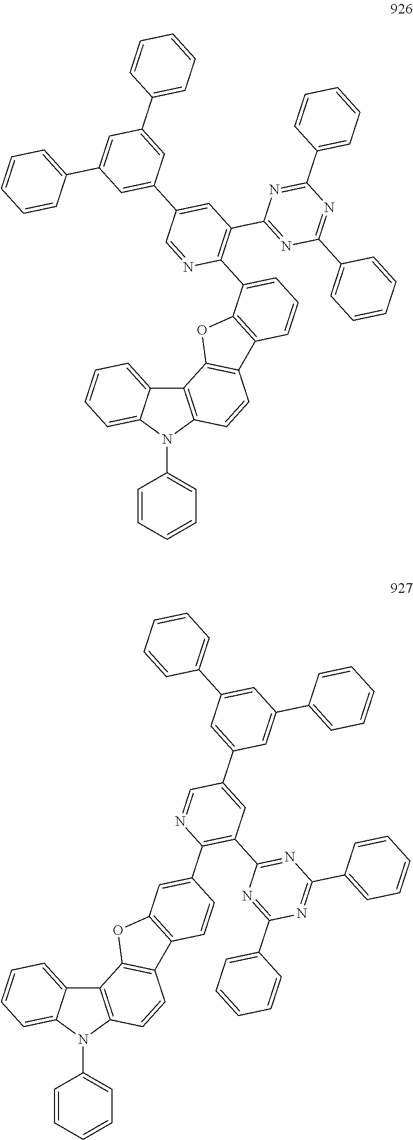 [SMILES: c1ccc(-c2cc(-c3ccccc3)cc(-c3cnc(-c4cccc5c4oc4c5ccc5c4c4ccccc4n5-c4ccccc4)c(-c4nc(-c5ccccc5)nc(-c5ccccc5)n4)c3)c2)cc1 ; c1ccc(-c2cc(-c3ccccc3)cc(-c3cnc(-c4ccc5c(c4)oc4c5ccc5c4c4ccccc4n5-c4ccccc4)c(-c4nc(-c5ccccc5)nc(-c5ccccc5)n4)c3)c2)cc1]

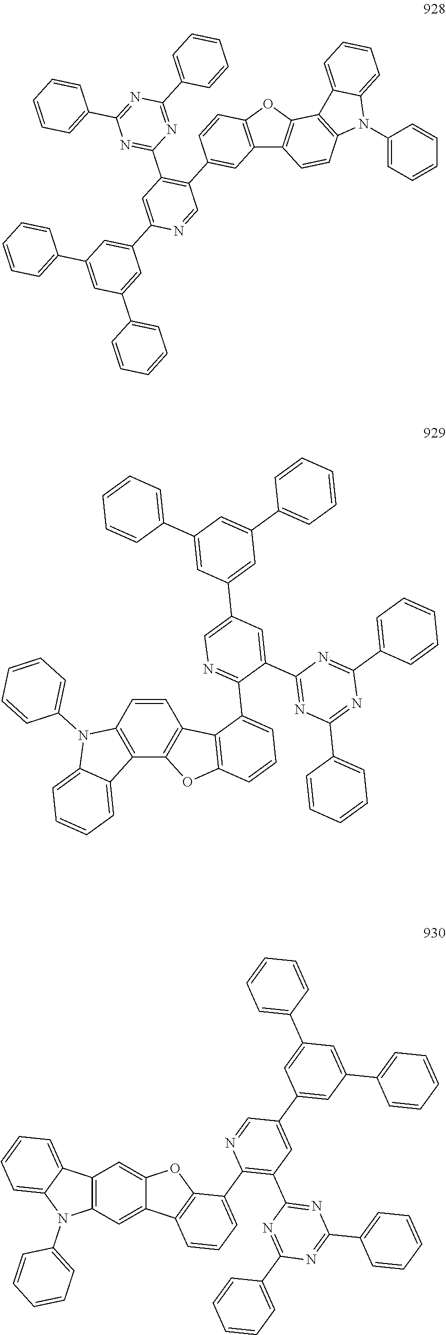 [SMILES: c1ccc(-c2cc(-c3ccccc3)cc(-c3cc(-c4nc(-c5ccccc5)nc(-c5ccccc5)n4)c(-c4ccc5oc6c(ccc7c6c6ccccc6n7-c6ccccc6)c5c4)cn3)c2)cc1 ; c1ccc(-c2cc(-c3ccccc3)cc(-c3cnc(-c4cccc5oc6c(ccc7c6c6ccccc6n7-c6ccccc6)c45)c(-c4nc(-c5ccccc5)nc(-c5ccccc5)n4)c3)c2)cc1 ; c1ccc(-c2cc(-c3ccccc3)cc(-c3cnc(-c4cccc5c4oc4cc6c7ccccc7n(-c7ccccc7)c6cc45)c(-c4nc(-c5ccccc5)nc(-c5ccccc5)n4)c3)c2)cc1]

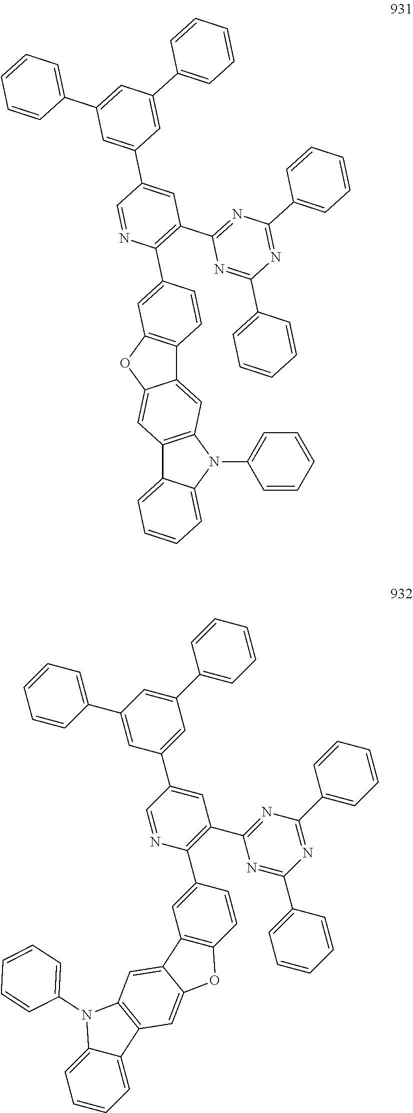 [SMILES: c1ccc(-c2cc(-c3ccccc3)cc(-c3cnc(-c4ccc5c(c4)oc4cc6c7ccccc7n(-c7ccccc7)c6cc45)c(-c4nc(-c5ccccc5)nc(-c5ccccc5)n4)c3)c2)cc1 ; c1ccc(-c2cc(-c3ccccc3)cc(-c3cnc(-c4ccc5oc6cc7c8ccccc8n(-c8ccccc8)c7cc6c5c4)c(-c4nc(-c5ccccc5)nc(-c5ccccc5)n4)c3)c2)cc1]

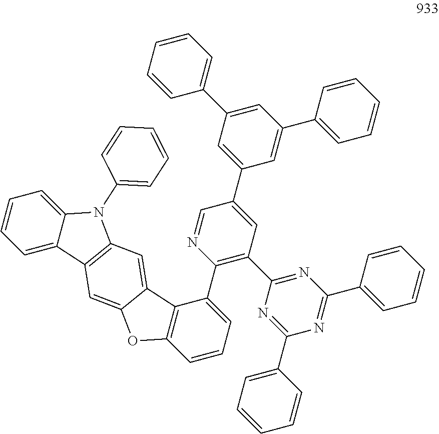 [SMILES: c1ccc(-c2cc(-c3ccccc3)cc(-c3cnc(-c4cccc5oc6cc7c8ccccc8n(-c8ccccc8)c7cc6c45)c(-c4nc(-c5ccccc5)nc(-c5ccccc5)n4)c3)c2)cc1]

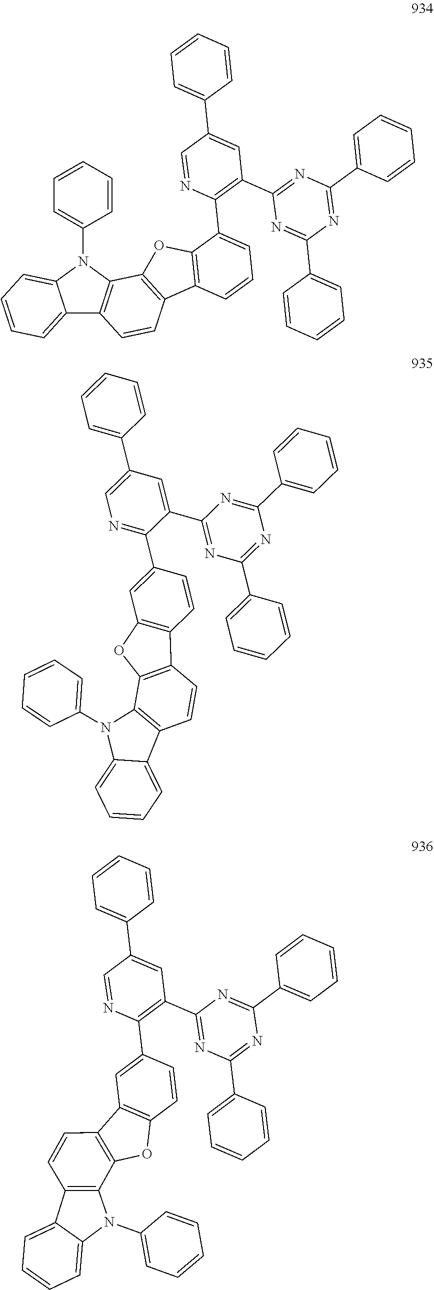

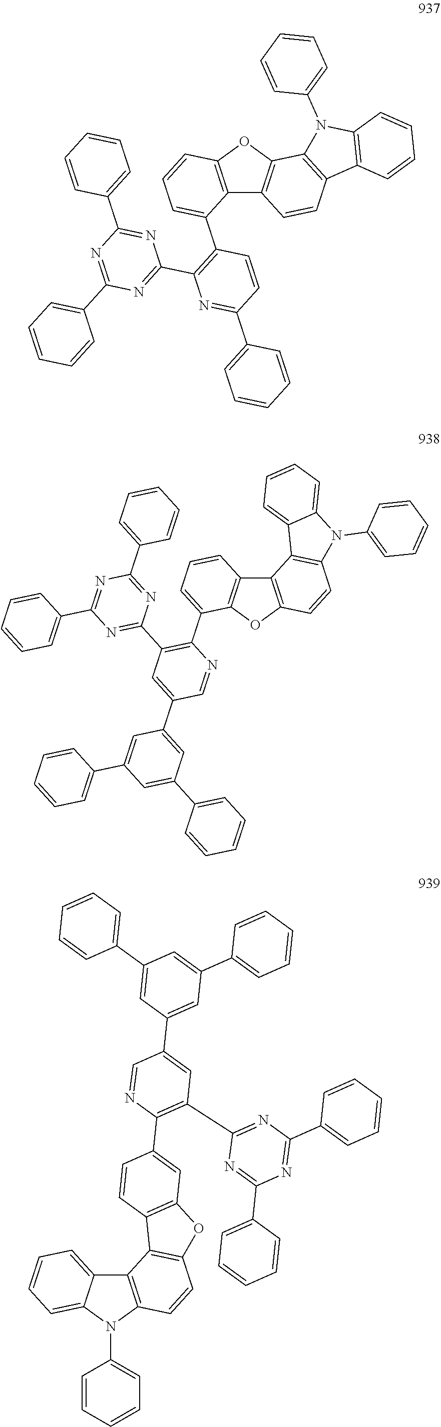 [SMILES: c1ccc(-c2ccc(-c3cccc4oc5c(ccc6c7ccccc7n(-c7ccccc7)c65)c34)c(-c3nc(-c4ccccc4)nc(-c4ccccc4)n3)n2)cc1 ; c1ccc(-c2cc(-c3ccccc3)cc(-c3cnc(-c4cccc5c4oc4ccc6c(c7ccccc7n6-c6ccccc6)c45)c(-c4nc(-c5ccccc5)nc(-c5ccccc5)n4)c3)c2)cc1 ; c1ccc(-c2cc(-c3ccccc3)cc(-c3cnc(-c4ccc5c(c4)oc4ccc6c(c7ccccc7n6-c6ccccc6)c45)c(-c4nc(-c5ccccc5)nc(-c5ccccc5)n4)c3)c2)cc1]

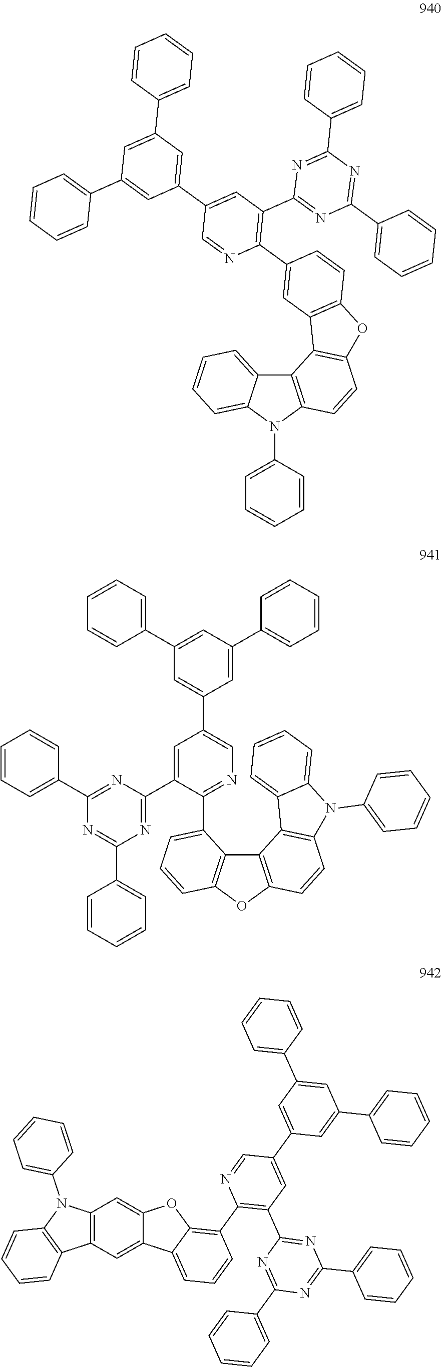 [SMILES: c1ccc(-c2cc(-c3ccccc3)cc(-c3cnc(-c4ccc5oc6ccc7c(c8ccccc8n7-c7ccccc7)c6c5c4)c(-c4nc(-c5ccccc5)nc(-c5ccccc5)n4)c3)c2)cc1 ; c1ccc(-c2cc(-c3ccccc3)cc(-c3cnc(-c4cccc5oc6ccc7c(c8ccccc8n7-c7ccccc7)c6c45)c(-c4nc(-c5ccccc5)nc(-c5ccccc5)n4)c3)c2)cc1 ; c1ccc(-c2cc(-c3ccccc3)cc(-c3cnc(-c4cccc5c4oc4cc6c(cc45)c4ccccc4n6-c4ccccc4)c(-c4nc(-c5ccccc5)nc(-c5ccccc5)n4)c3)c2)cc1]

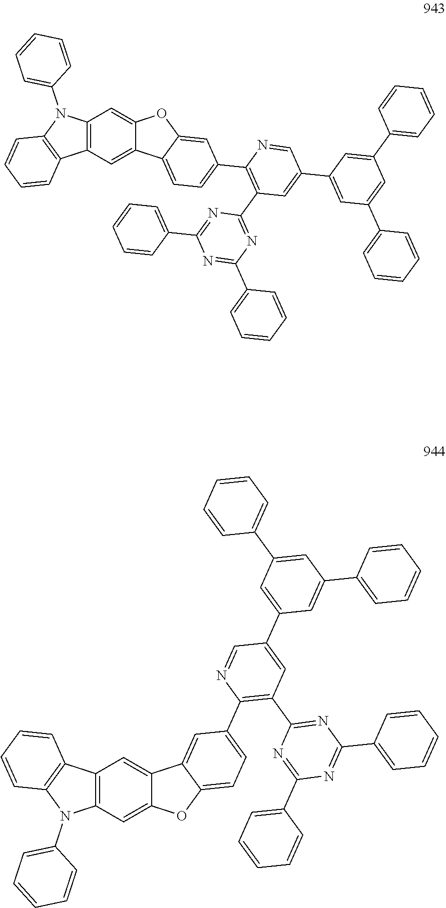 [SMILES: c1ccc(-c2cc(-c3ccccc3)cc(-c3cnc(-c4ccc5c(c4)oc4cc6c(cc45)c4ccccc4n6-c4ccccc4)c(-c4nc(-c5ccccc5)nc(-c5ccccc5)n4)c3)c2)cc1 ; c1ccc(-c2cc(-c3ccccc3)cc(-c3cnc(-c4ccc5oc6cc7c(cc6c5c4)c4ccccc4n7-c4ccccc4)c(-c4nc(-c5ccccc5)nc(-c5ccccc5)n4)c3)c2)cc1]

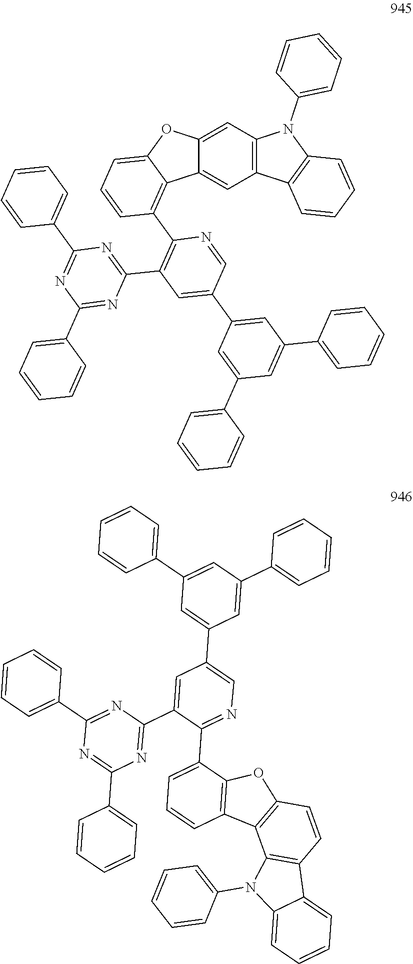 [SMILES: c1ccc(-c2cc(-c3ccccc3)cc(-c3cnc(-c4cccc5oc6cc7c(cc6c45)c4ccccc4n7-c4ccccc4)c(-c4nc(-c5ccccc5)nc(-c5ccccc5)n4)c3)c2)cc1 ; c1ccc(-c2cc(-c3ccccc3)cc(-c3cnc(-c4cccc5c4oc4ccc6c7ccccc7n(-c7ccccc7)c6c45)c(-c4nc(-c5ccccc5)nc(-c5ccccc5)n4)c3)c2)cc1]

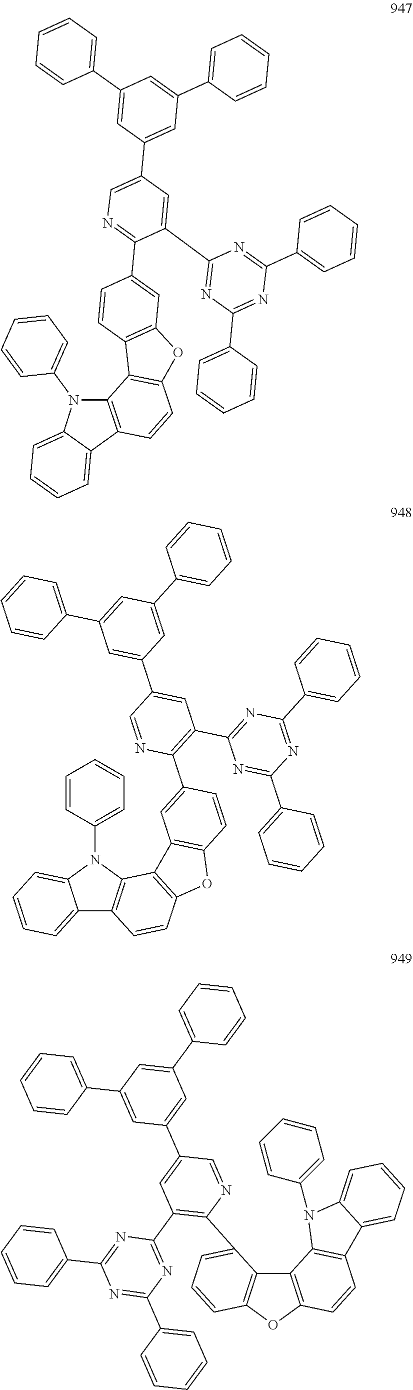 [SMILES: c1ccc(-c2cc(-c3ccccc3)cc(-c3cnc(-c4ccc5c(c4)oc4ccc6c7ccccc7n(-c7ccccc7)c6c45)c(-c4nc(-c5ccccc5)nc(-c5ccccc5)n4)c3)c2)cc1 ; c1ccc(-c2cc(-c3ccccc3)cc(-c3cnc(-c4ccc5oc6ccc7c8ccccc8n(-c8ccccc8)c7c6c5c4)c(-c4nc(-c5ccccc5)nc(-c5ccccc5)n4)c3)c2)cc1 ; c1ccc(-c2cc(-c3ccccc3)cc(-c3cnc(-c4cccc5oc6ccc7c8ccccc8n(-c8ccccc8)c7c6c45)c(-c4nc(-c5ccccc5)nc(-c5ccccc5)n4)c3)c2)cc1]

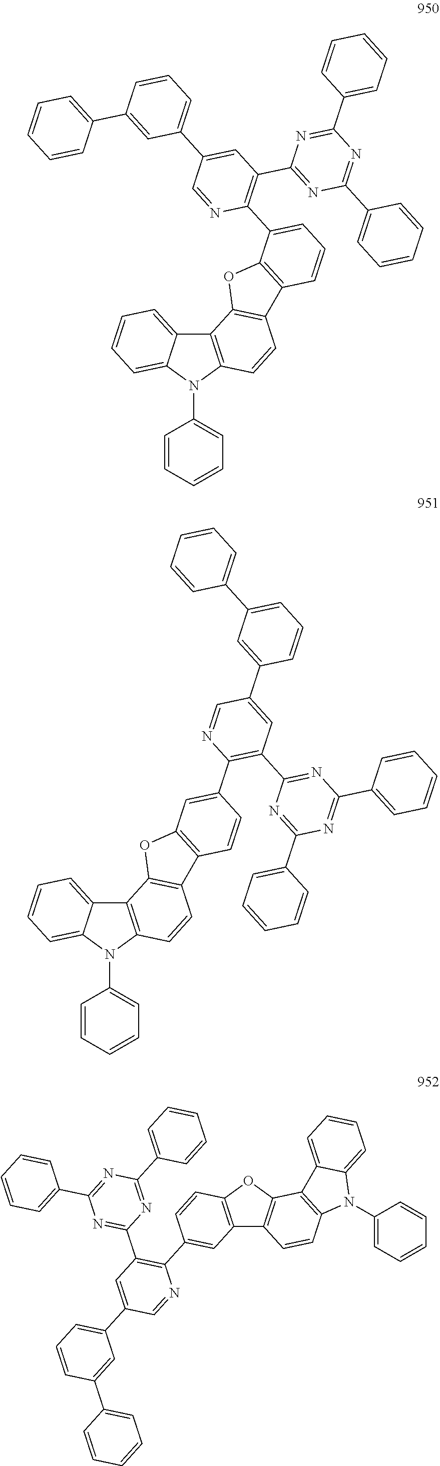 [SMILES: c1ccc(-c2cccc(-c3cnc(-c4cccc5c4oc4c5ccc5c4c4ccccc4n5-c4ccccc4)c(-c4nc(-c5ccccc5)nc(-c5ccccc5)n4)c3)c2)cc1 ; c1ccc(-c2cccc(-c3cnc(-c4ccc5c(c4)oc4c5ccc5c4c4ccccc4n5-c4ccccc4)c(-c4nc(-c5ccccc5)nc(-c5ccccc5)n4)c3)c2)cc1 ; c1ccc(-c2cccc(-c3cnc(-c4ccc5oc6c(ccc7c6c6ccccc6n7-c6ccccc6)c5c4)c(-c4nc(-c5ccccc5)nc(-c5ccccc5)n4)c3)c2)cc1]

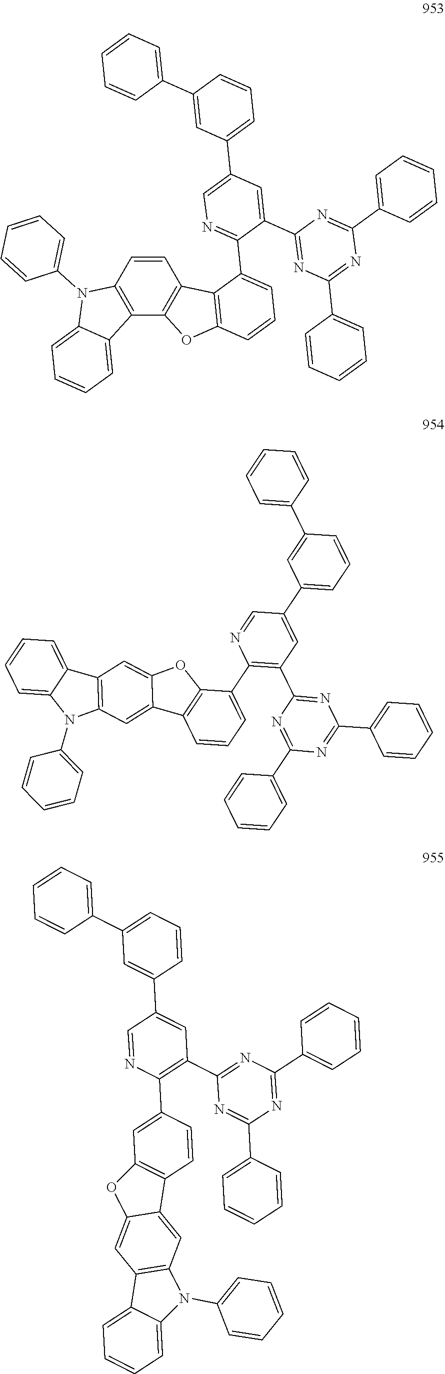 [SMILES: c1ccc(-c2cccc(-c3cnc(-c4cccc5oc6c(ccc7c6c6ccccc6n7-c6ccccc6)c45)c(-c4nc(-c5ccccc5)nc(-c5ccccc5)n4)c3)c2)cc1 ; c1ccc(-c2cccc(-c3cnc(-c4cccc5c4oc4cc6c7ccccc7n(-c7ccccc7)c6cc45)c(-c4nc(-c5ccccc5)nc(-c5ccccc5)n4)c3)c2)cc1 ; c1ccc(-c2cccc(-c3cnc(-c4ccc5c(c4)oc4cc6c7ccccc7n(-c7ccccc7)c6cc45)c(-c4nc(-c5ccccc5)nc(-c5ccccc5)n4)c3)c2)cc1]

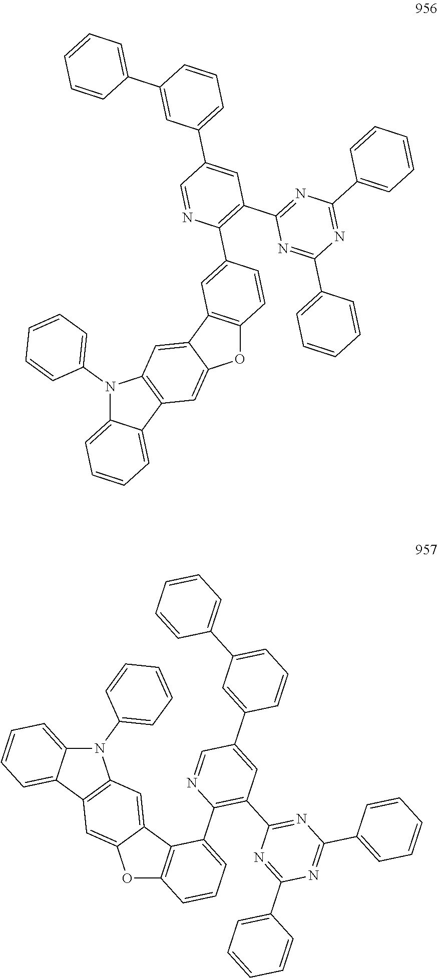 [SMILES: c1ccc(-c2cccc(-c3cnc(-c4ccc5oc6cc7c8ccccc8n(-c8ccccc8)c7cc6c5c4)c(-c4nc(-c5ccccc5)nc(-c5ccccc5)n4)c3)c2)cc1 ; c1ccc(-c2cccc(-c3cnc(-c4cccc5oc6cc7c8ccccc8n(-c8ccccc8)c7cc6c45)c(-c4nc(-c5ccccc5)nc(-c5ccccc5)n4)c3)c2)cc1]

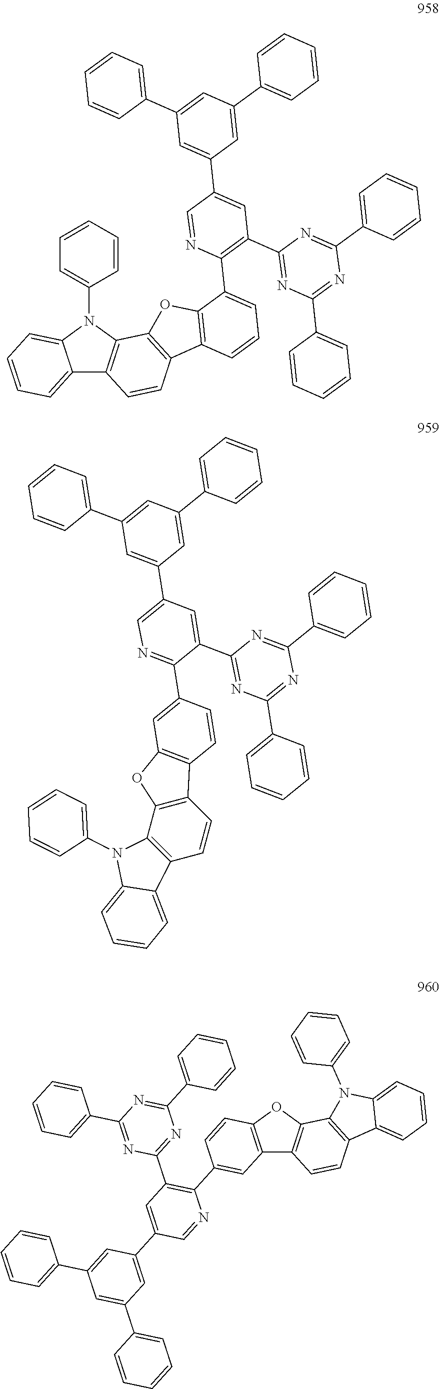 [SMILES: c1ccc(-c2cc(-c3ccccc3)cc(-c3cnc(-c4cccc5c4oc4c5ccc5c6ccccc6n(-c6ccccc6)c54)c(-c4nc(-c5ccccc5)nc(-c5ccccc5)n4)c3)c2)cc1 ; c1ccc(-c2cc(-c3ccccc3)cc(-c3cnc(-c4ccc5c(c4)oc4c5ccc5c6ccccc6n(-c6ccccc6)c54)c(-c4nc(-c5ccccc5)nc(-c5ccccc5)n4)c3)c2)cc1 ; c1ccc(-c2cc(-c3ccccc3)cc(-c3cnc(-c4ccc5oc6c(ccc7c8ccccc8n(-c8ccccc8)c76)c5c4)c(-c4nc(-c5ccccc5)nc(-c5ccccc5)n4)c3)c2)cc1]

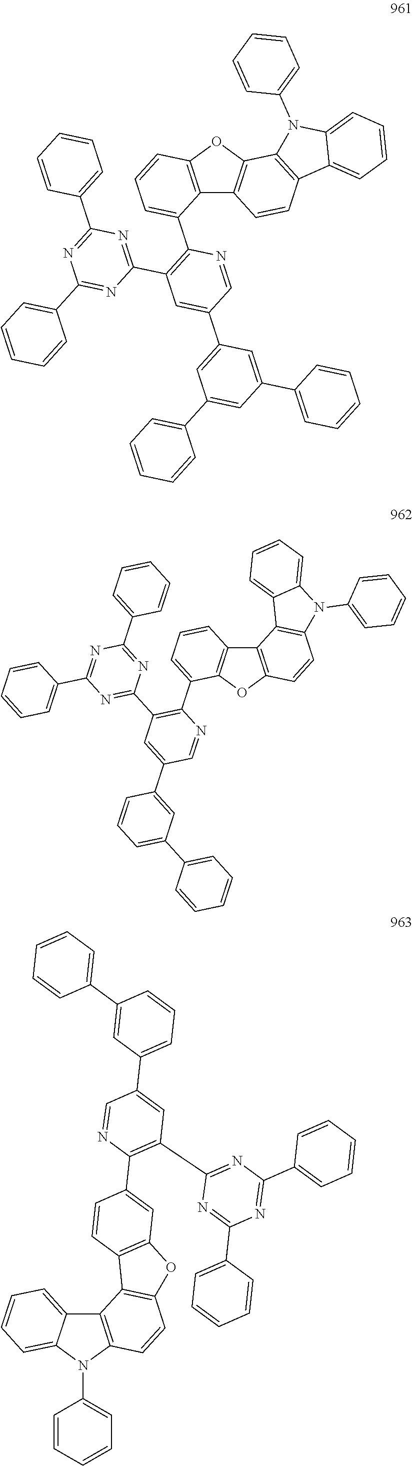 [SMILES: c1ccc(-c2cc(-c3ccccc3)cc(-c3cnc(-c4cccc5oc6c(ccc7c8ccccc8n(-c8ccccc8)c76)c45)c(-c4nc(-c5ccccc5)nc(-c5ccccc5)n4)c3)c2)cc1 ; c1ccc(-c2cccc(-c3cnc(-c4cccc5c4oc4ccc6c(c7ccccc7n6-c6ccccc6)c45)c(-c4nc(-c5ccccc5)nc(-c5ccccc5)n4)c3)c2)cc1 ; c1ccc(-c2cccc(-c3cnc(-c4ccc5c(c4)oc4ccc6c(c7ccccc7n6-c6ccccc6)c45)c(-c4nc(-c5ccccc5)nc(-c5ccccc5)n4)c3)c2)cc1]

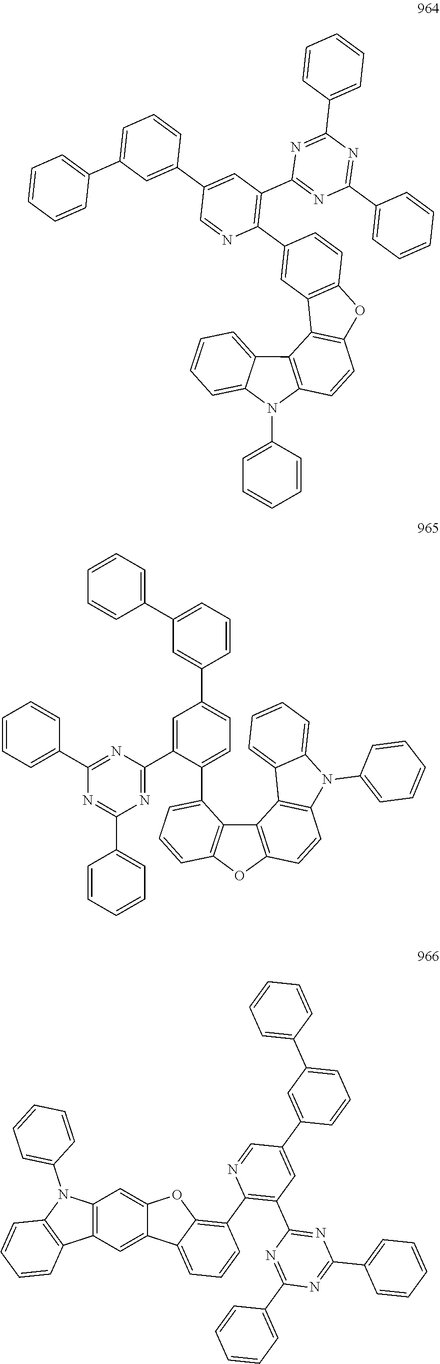 [SMILES: c1ccc(-c2cccc(-c3cnc(-c4ccc5oc6ccc7c(c8ccccc8n7-c7ccccc7)c6c5c4)c(-c4nc(-c5ccccc5)nc(-c5ccccc5)n4)c3)c2)cc1 ; c1ccc(-c2cccc(-c3ccc(-c4cccc5oc6ccc7c(c8ccccc8n7-c7ccccc7)c6c45)c(-c4nc(-c5ccccc5)nc(-c5ccccc5)n4)c3)c2)cc1 ; c1ccc(-c2cccc(-c3cnc(-c4cccc5c4oc4cc6c(cc45)c4ccccc4n6-c4ccccc4)c(-c4nc(-c5ccccc5)nc(-c5ccccc5)n4)c3)c2)cc1]

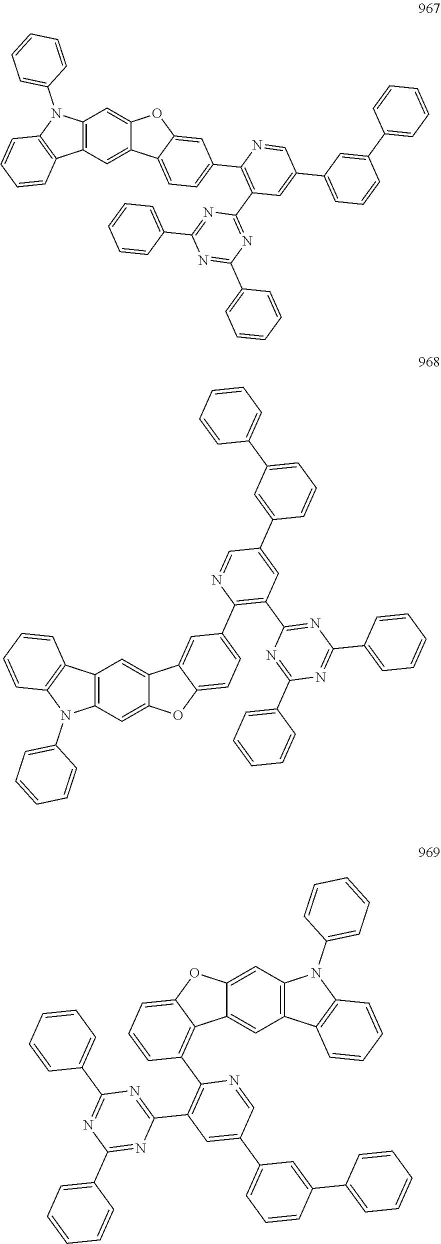 [SMILES: c1ccc(-c2cccc(-c3cnc(-c4ccc5c(c4)oc4cc6c(cc45)c4ccccc4n6-c4ccccc4)c(-c4nc(-c5ccccc5)nc(-c5ccccc5)n4)c3)c2)cc1 ; c1ccc(-c2cccc(-c3cnc(-c4ccc5oc6cc7c(cc6c5c4)c4ccccc4n7-c4ccccc4)c(-c4nc(-c5ccccc5)nc(-c5ccccc5)n4)c3)c2)cc1 ; c1ccc(-c2cccc(-c3cnc(-c4cccc5oc6cc7c(cc6c45)c4ccccc4n7-c4ccccc4)c(-c4nc(-c5ccccc5)nc(-c5ccccc5)n4)c3)c2)cc1]

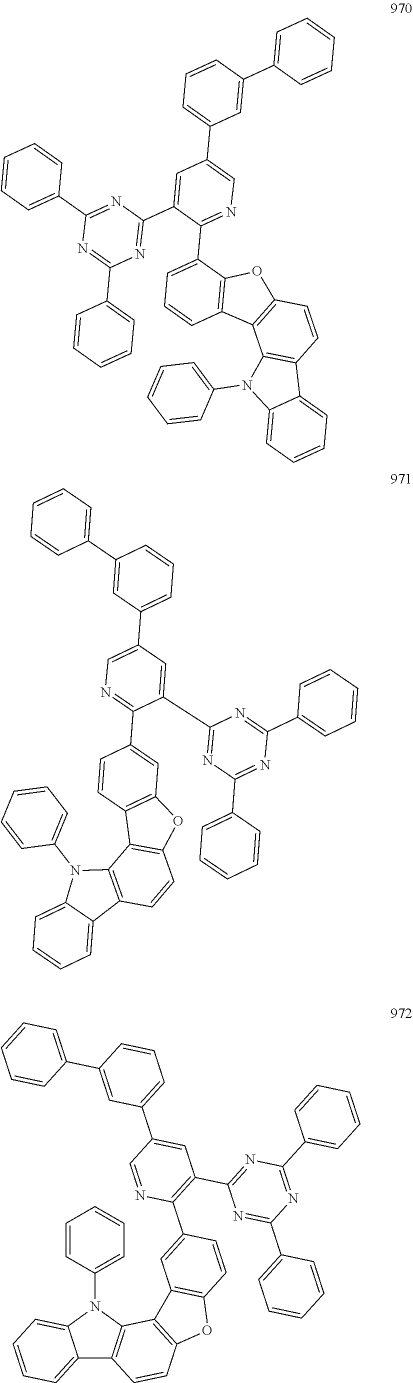 [SMILES: c1ccc(-c2cccc(-c3cnc(-c4cccc5c4oc4ccc6c7ccccc7n(-c7ccccc7)c6c45)c(-c4nc(-c5ccccc5)nc(-c5ccccc5)n4)c3)c2)cc1 ; c1ccc(-c2cccc(-c3cnc(-c4ccc5c(c4)oc4ccc6c7ccccc7n(-c7ccccc7)c6c45)c(-c4nc(-c5ccccc5)nc(-c5ccccc5)n4)c3)c2)cc1 ; c1ccc(-c2cccc(-c3cnc(-c4ccc5oc6ccc7c8ccccc8n(-c8ccccc8)c7c6c5c4)c(-c4nc(-c5ccccc5)nc(-c5ccccc5)n4)c3)c2)cc1]

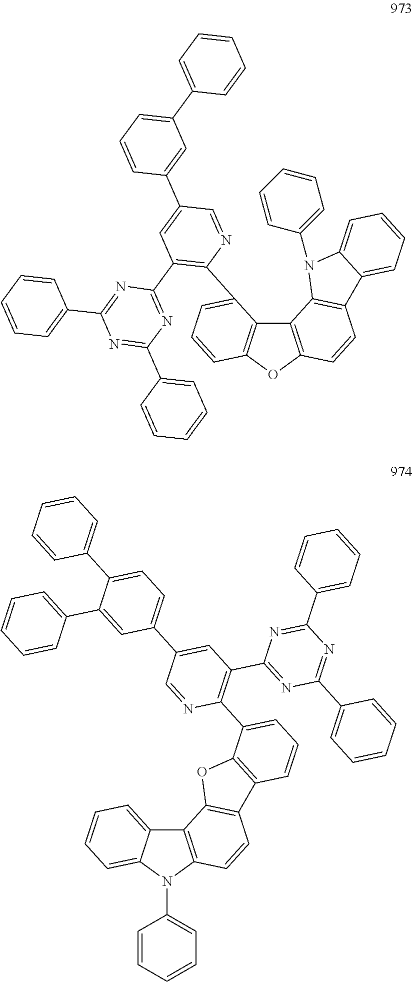 [SMILES: c1ccc(-c2cccc(-c3cnc(-c4cccc5oc6ccc7c8ccccc8n(-c8ccccc8)c7c6c45)c(-c4nc(-c5ccccc5)nc(-c5ccccc5)n4)c3)c2)cc1 ; c1ccc(-c2nc(-c3ccccc3)nc(-c3cc(-c4ccc(-c5ccccc5)c(-c5ccccc5)c4)cnc3-c3cccc4c3oc3c4ccc4c3c3ccccc3n4-c3ccccc3)n2)cc1]

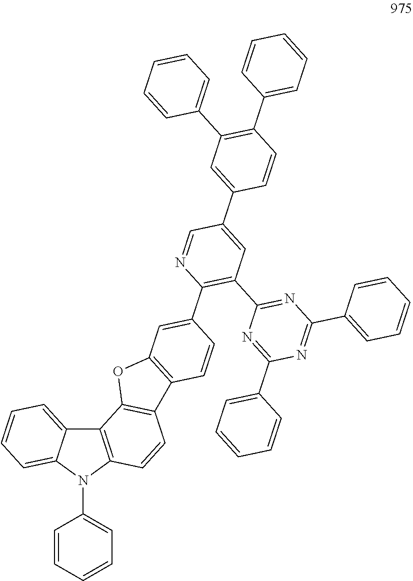 [SMILES: c1ccc(-c2nc(-c3ccccc3)nc(-c3cc(-c4ccc(-c5ccccc5)c(-c5ccccc5)c4)cnc3-c3ccc4c(c3)oc3c4ccc4c3c3ccccc3n4-c3ccccc3)n2)cc1]

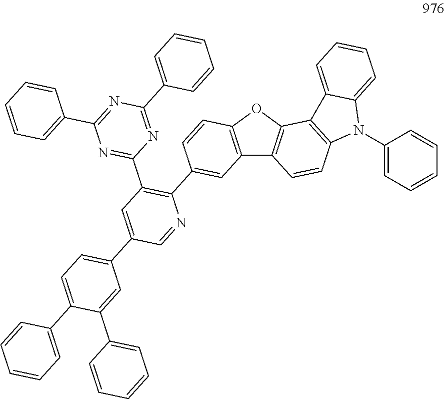 [SMILES: c1ccc(-c2nc(-c3ccccc3)nc(-c3cc(-c4ccc(-c5ccccc5)c(-c5ccccc5)c4)cnc3-c3ccc4oc5c(ccc6c5c5ccccc5n6-c5ccccc5)c4c3)n2)cc1]

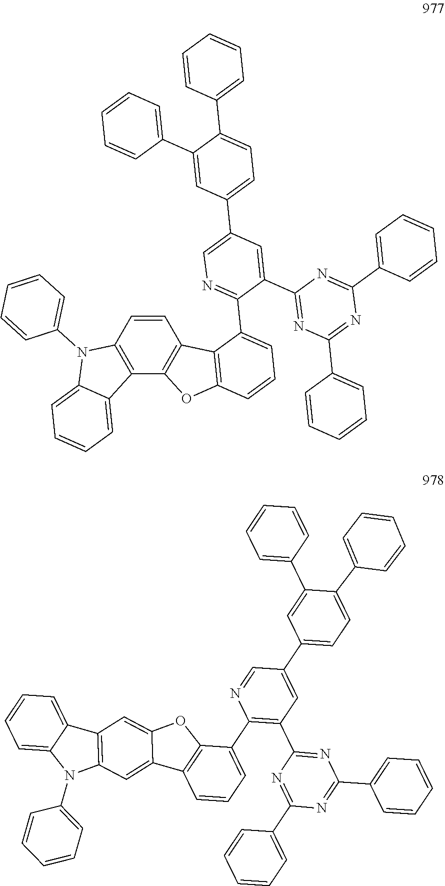 [SMILES: c1ccc(-c2nc(-c3ccccc3)nc(-c3cc(-c4ccc(-c5ccccc5)c(-c5ccccc5)c4)cnc3-c3cccc4oc5c(ccc6c5c5ccccc5n6-c5ccccc5)c34)n2)cc1 ; c1ccc(-c2nc(-c3ccccc3)nc(-c3cc(-c4ccc(-c5ccccc5)c(-c5ccccc5)c4)cnc3-c3cccc4c3oc3cc5c6ccccc6n(-c6ccccc6)c5cc34)n2)cc1]

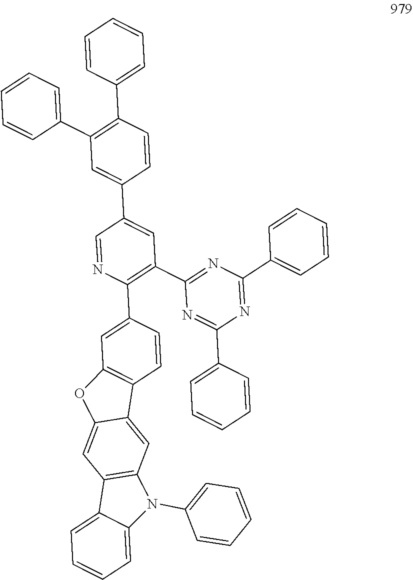 [SMILES: c1ccc(-c2nc(-c3ccccc3)nc(-c3cc(-c4ccc(-c5ccccc5)c(-c5ccccc5)c4)cnc3-c3ccc4c(c3)oc3cc5c6ccccc6n(-c6ccccc6)c5cc34)n2)cc1]

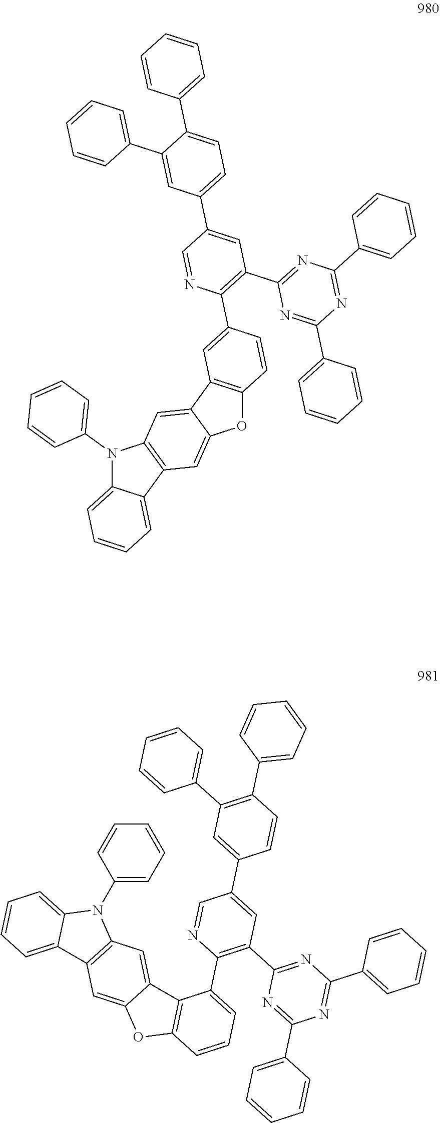 [SMILES: c1ccc(-c2nc(-c3ccccc3)nc(-c3cc(-c4ccc(-c5ccccc5)c(-c5ccccc5)c4)cnc3-c3ccc4oc5cc6c7ccccc7n(-c7ccccc7)c6cc5c4c3)n2)cc1 ; c1ccc(-c2nc(-c3ccccc3)nc(-c3cc(-c4ccc(-c5ccccc5)c(-c5ccccc5)c4)cnc3-c3cccc4oc5cc6c7ccccc7n(-c7ccccc7)c6cc5c34)n2)cc1]

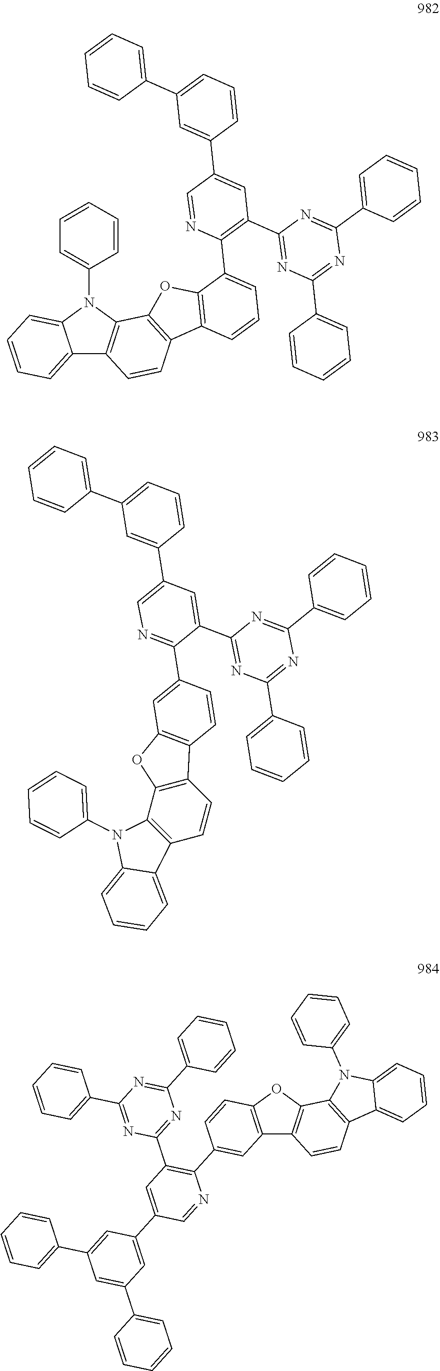 [SMILES: c1ccc(-c2cccc(-c3cnc(-c4cccc5c4oc4c5ccc5c6ccccc6n(-c6ccccc6)c54)c(-c4nc(-c5ccccc5)nc(-c5ccccc5)n4)c3)c2)cc1 ; c1ccc(-c2cccc(-c3cnc(-c4ccc5c(c4)oc4c5ccc5c6ccccc6n(-c6ccccc6)c54)c(-c4nc(-c5ccccc5)nc(-c5ccccc5)n4)c3)c2)cc1 ; c1ccc(-c2cc(-c3ccccc3)cc(-c3cnc(-c4ccc5oc6c(ccc7c8ccccc8n(-c8ccccc8)c76)c5c4)c(-c4nc(-c5ccccc5)nc(-c5ccccc5)n4)c3)c2)cc1]

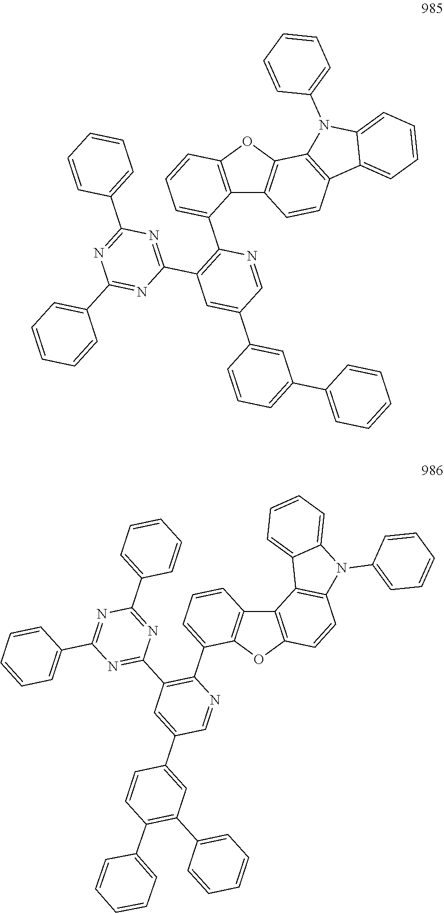 [SMILES: c1ccc(-c2cccc(-c3cnc(-c4cccc5oc6c(ccc7c8ccccc8n(-c8ccccc8)c76)c45)c(-c4nc(-c5ccccc5)nc(-c5ccccc5)n4)c3)c2)cc1 ; c1ccc(-c2nc(-c3ccccc3)nc(-c3cc(-c4ccc(-c5ccccc5)c(-c5ccccc5)c4)cnc3-c3cccc4c3oc3ccc5c(c6ccccc6n5-c5ccccc5)c34)n2)cc1]

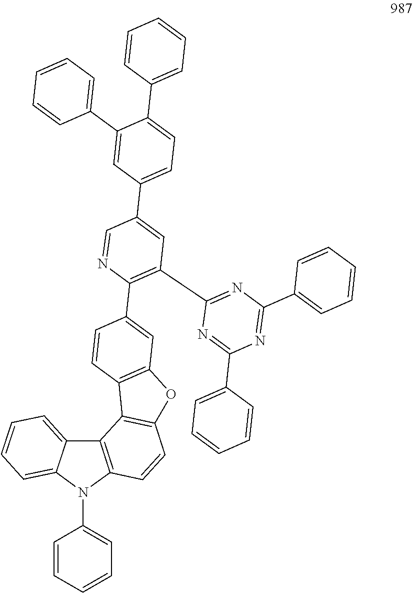 [SMILES: c1ccc(-c2nc(-c3ccccc3)nc(-c3cc(-c4ccc(-c5ccccc5)c(-c5ccccc5)c4)cnc3-c3ccc4c(c3)oc3ccc5c(c6ccccc6n5-c5ccccc5)c34)n2)cc1]

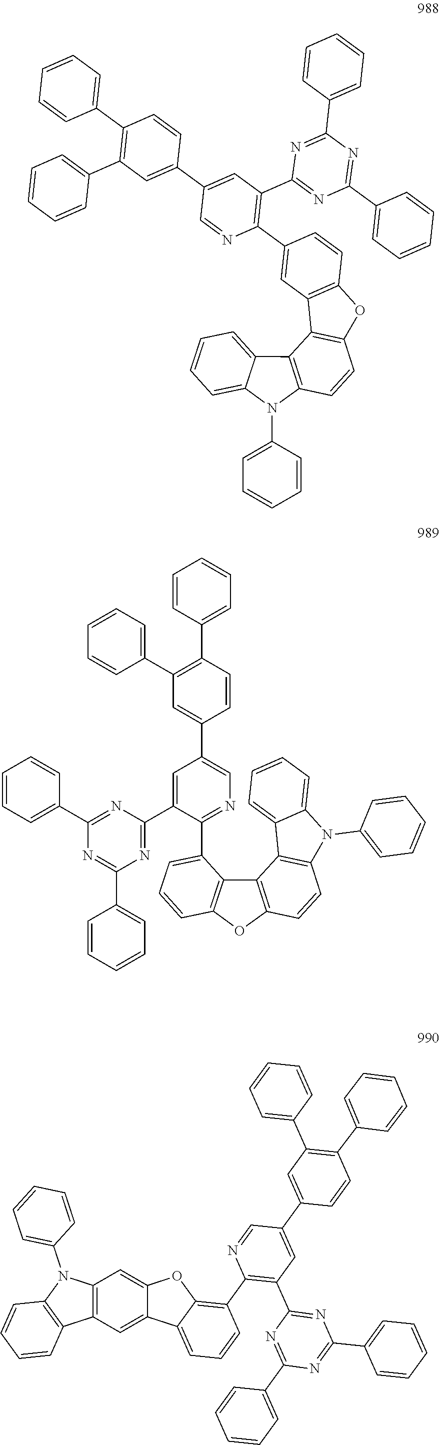 [SMILES: c1ccc(-c2nc(-c3ccccc3)nc(-c3cc(-c4ccc(-c5ccccc5)c(-c5ccccc5)c4)cnc3-c3ccc4oc5ccc6c(c7ccccc7n6-c6ccccc6)c5c4c3)n2)cc1 ; c1ccc(-c2nc(-c3ccccc3)nc(-c3cc(-c4ccc(-c5ccccc5)c(-c5ccccc5)c4)cnc3-c3cccc4oc5ccc6c(c7ccccc7n6-c6ccccc6)c5c34)n2)cc1 ; c1ccc(-c2nc(-c3ccccc3)nc(-c3cc(-c4ccc(-c5ccccc5)c(-c5ccccc5)c4)cnc3-c3cccc4c3oc3cc5c(cc34)c3ccccc3n5-c3ccccc3)n2)cc1]

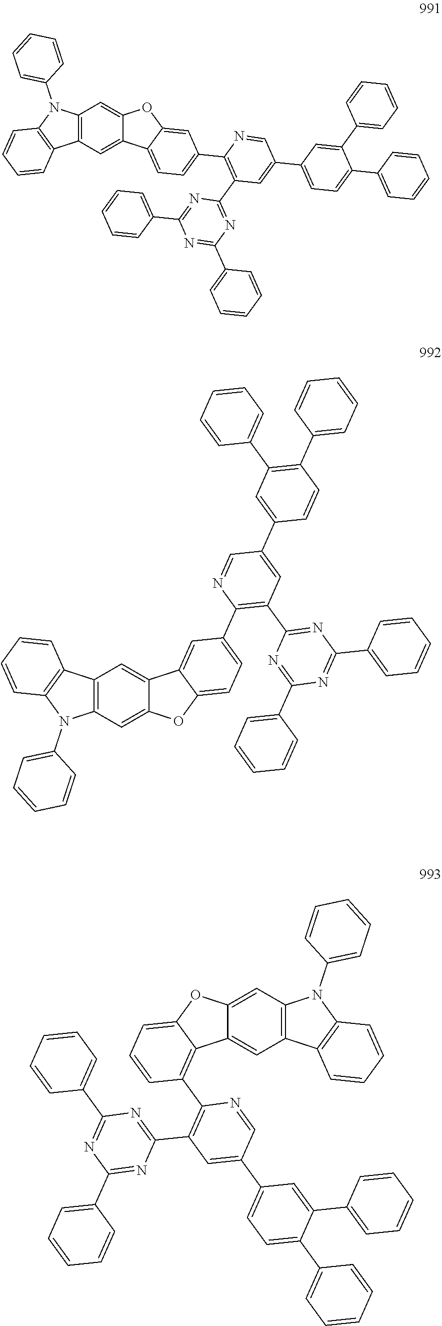 [SMILES: c1ccc(-c2nc(-c3ccccc3)nc(-c3cc(-c4ccc(-c5ccccc5)c(-c5ccccc5)c4)cnc3-c3ccc4c(c3)oc3cc5c(cc34)c3ccccc3n5-c3ccccc3)n2)cc1 ; c1ccc(-c2nc(-c3ccccc3)nc(-c3cc(-c4ccc(-c5ccccc5)c(-c5ccccc5)c4)cnc3-c3ccc4oc5cc6c(cc5c4c3)c3ccccc3n6-c3ccccc3)n2)cc1 ; c1ccc(-c2nc(-c3ccccc3)nc(-c3cc(-c4ccc(-c5ccccc5)c(-c5ccccc5)c4)cnc3-c3cccc4oc5cc6c(cc5c34)c3ccccc3n6-c3ccccc3)n2)cc1]

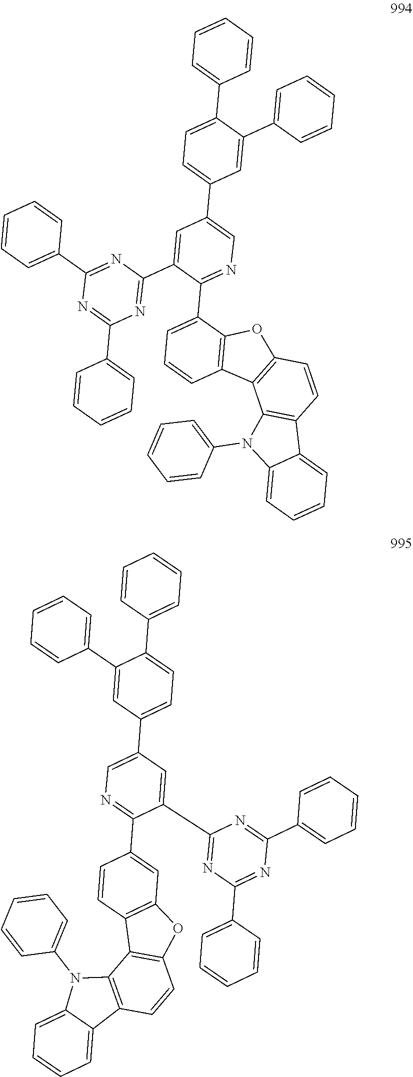 [SMILES: c1ccc(-c2nc(-c3ccccc3)nc(-c3cc(-c4ccc(-c5ccccc5)c(-c5ccccc5)c4)cnc3-c3cccc4c3oc3ccc5c6ccccc6n(-c6ccccc6)c5c34)n2)cc1 ; c1ccc(-c2nc(-c3ccccc3)nc(-c3cc(-c4ccc(-c5ccccc5)c(-c5ccccc5)c4)cnc3-c3ccc4c(c3)oc3ccc5c6ccccc6n(-c6ccccc6)c5c34)n2)cc1]

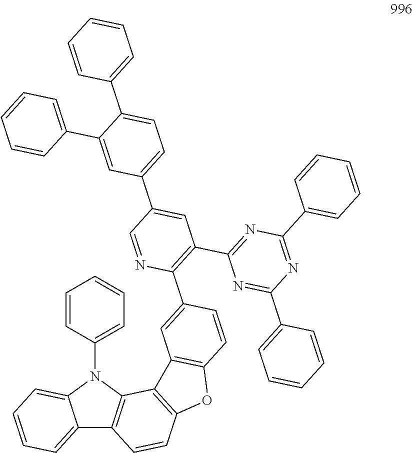 [SMILES: c1ccc(-c2nc(-c3ccccc3)nc(-c3cc(-c4ccc(-c5ccccc5)c(-c5ccccc5)c4)cnc3-c3ccc4oc5ccc6c7ccccc7n(-c7ccccc7)c6c5c4c3)n2)cc1]

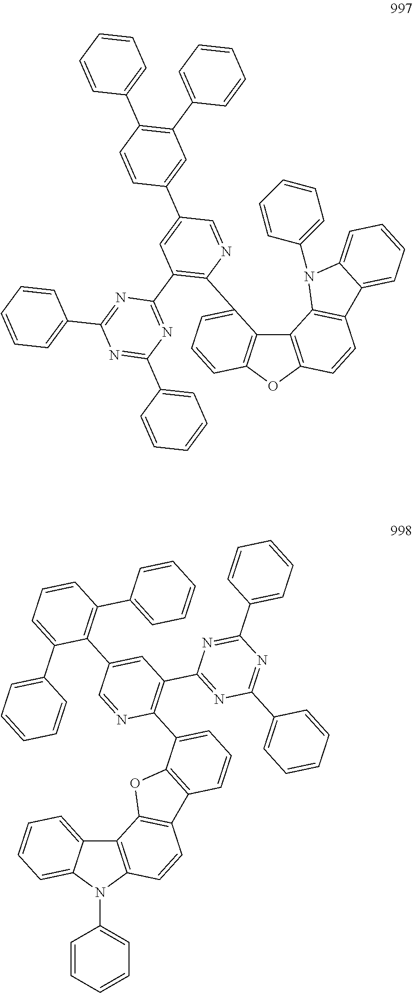 [SMILES: c1ccc(-c2nc(-c3ccccc3)nc(-c3cc(-c4ccc(-c5ccccc5)c(-c5ccccc5)c4)cnc3-c3cccc4oc5ccc6c7ccccc7n(-c7ccccc7)c6c5c34)n2)cc1 ; c1ccc(-c2nc(-c3ccccc3)nc(-c3cc(-c4c(-c5ccccc5)cccc4-c4ccccc4)cnc3-c3cccc4c3oc3c4ccc4c3c3ccccc3n4-c3ccccc3)n2)cc1]

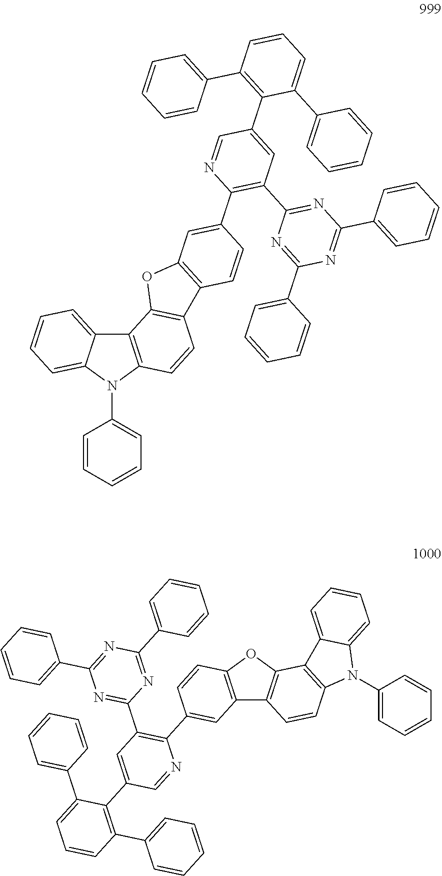 [SMILES: c1ccc(-c2nc(-c3ccccc3)nc(-c3cc(-c4c(-c5ccccc5)cccc4-c4ccccc4)cnc3-c3ccc4c(c3)oc3c4ccc4c3c3ccccc3n4-c3ccccc3)n2)cc1 ; c1ccc(-c2nc(-c3ccccc3)nc(-c3cc(-c4c(-c5ccccc5)cccc4-c4ccccc4)cnc3-c3ccc4oc5c(ccc6c5c5ccccc5n6-c5ccccc5)c4c3)n2)cc1]

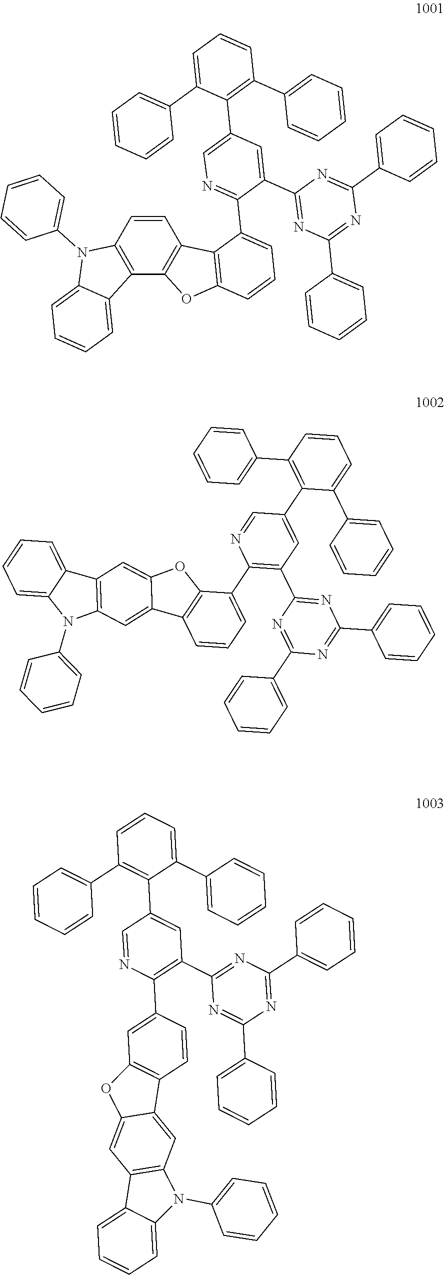 [SMILES: c1ccc(-c2nc(-c3ccccc3)nc(-c3cc(-c4c(-c5ccccc5)cccc4-c4ccccc4)cnc3-c3cccc4oc5c(ccc6c5c5ccccc5n6-c5ccccc5)c34)n2)cc1 ; c1ccc(-c2nc(-c3ccccc3)nc(-c3cc(-c4c(-c5ccccc5)cccc4-c4ccccc4)cnc3-c3cccc4c3oc3cc5c6ccccc6n(-c6ccccc6)c5cc34)n2)cc1 ; c1ccc(-c2nc(-c3ccccc3)nc(-c3cc(-c4c(-c5ccccc5)cccc4-c4ccccc4)cnc3-c3ccc4c(c3)oc3cc5c6ccccc6n(-c6ccccc6)c5cc34)n2)cc1]

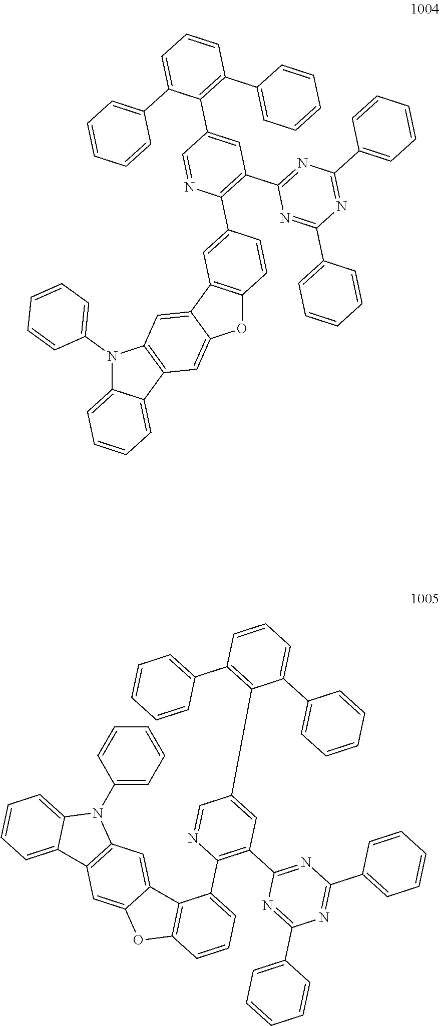 [SMILES: c1ccc(-c2nc(-c3ccccc3)nc(-c3cc(-c4c(-c5ccccc5)cccc4-c4ccccc4)cnc3-c3ccc4oc5cc6c7ccccc7n(-c7ccccc7)c6cc5c4c3)n2)cc1 ; c1ccc(-c2nc(-c3ccccc3)nc(-c3cc(-c4c(-c5ccccc5)cccc4-c4ccccc4)cnc3-c3cccc4oc5cc6c7ccccc7n(-c7ccccc7)c6cc5c34)n2)cc1]

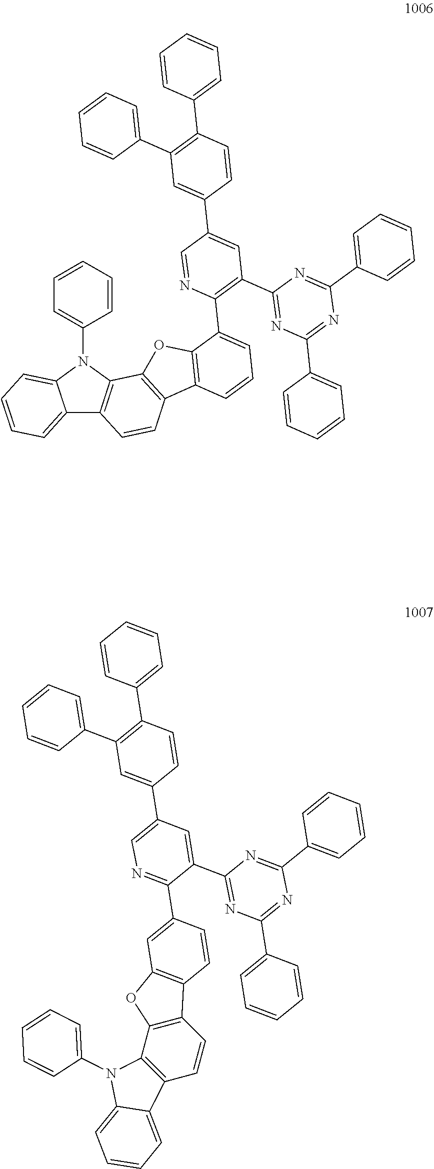 [SMILES: c1ccc(-c2nc(-c3ccccc3)nc(-c3cc(-c4ccc(-c5ccccc5)c(-c5ccccc5)c4)cnc3-c3cccc4c3oc3c4ccc4c5ccccc5n(-c5ccccc5)c43)n2)cc1 ; c1ccc(-c2nc(-c3ccccc3)nc(-c3cc(-c4ccc(-c5ccccc5)c(-c5ccccc5)c4)cnc3-c3ccc4c(c3)oc3c4ccc4c5ccccc5n(-c5ccccc5)c43)n2)cc1]

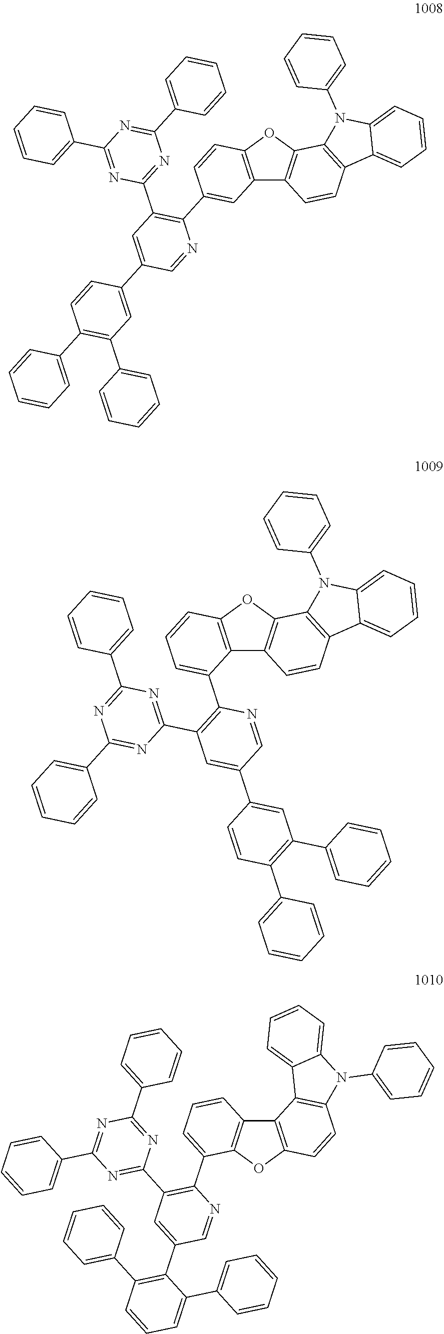 [SMILES: c1ccc(-c2nc(-c3ccccc3)nc(-c3cc(-c4ccc(-c5ccccc5)c(-c5ccccc5)c4)cnc3-c3ccc4oc5c(ccc6c7ccccc7n(-c7ccccc7)c65)c4c3)n2)cc1 ; c1ccc(-c2nc(-c3ccccc3)nc(-c3cc(-c4ccc(-c5ccccc5)c(-c5ccccc5)c4)cnc3-c3cccc4oc5c(ccc6c7ccccc7n(-c7ccccc7)c65)c34)n2)cc1 ; c1ccc(-c2nc(-c3ccccc3)nc(-c3cc(-c4c(-c5ccccc5)cccc4-c4ccccc4)cnc3-c3cccc4c3oc3ccc5c(c6ccccc6n5-c5ccccc5)c34)n2)cc1]

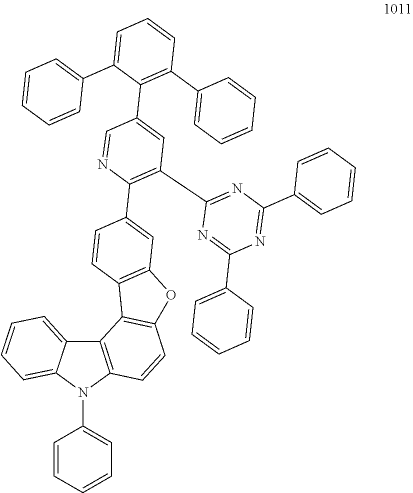 [SMILES: c1ccc(-c2nc(-c3ccccc3)nc(-c3cc(-c4c(-c5ccccc5)cccc4-c4ccccc4)cnc3-c3ccc4c(c3)oc3ccc5c(c6ccccc6n5-c5ccccc5)c34)n2)cc1]

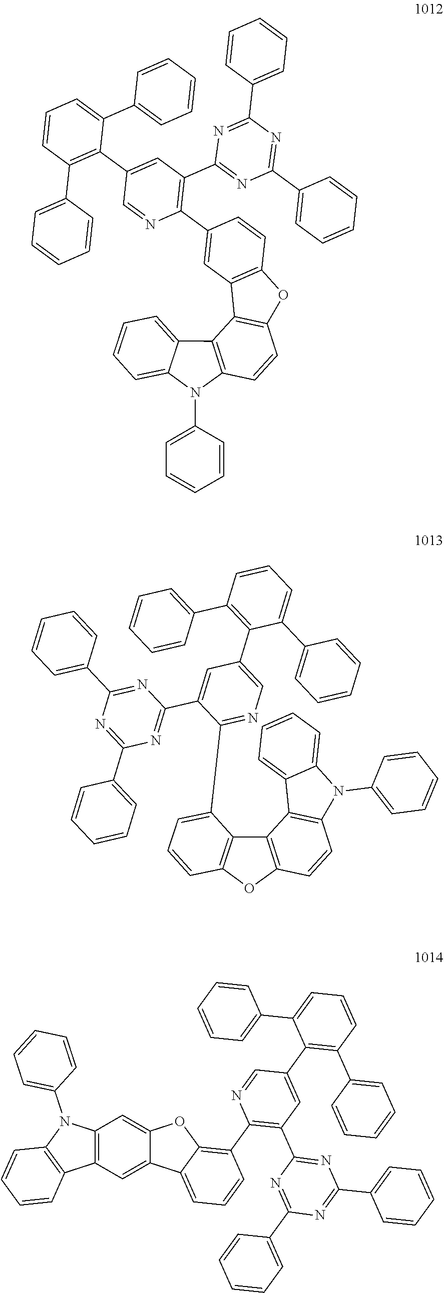 [SMILES: c1ccc(-c2nc(-c3ccccc3)nc(-c3cc(-c4c(-c5ccccc5)cccc4-c4ccccc4)cnc3-c3ccc4oc5ccc6c(c7ccccc7n6-c6ccccc6)c5c4c3)n2)cc1 ; c1ccc(-c2nc(-c3ccccc3)nc(-c3cc(-c4c(-c5ccccc5)cccc4-c4ccccc4)cnc3-c3cccc4oc5ccc6c(c7ccccc7n6-c6ccccc6)c5c34)n2)cc1 ; c1ccc(-c2nc(-c3ccccc3)nc(-c3cc(-c4c(-c5ccccc5)cccc4-c4ccccc4)cnc3-c3cccc4c3oc3cc5c(cc34)c3ccccc3n5-c3ccccc3)n2)cc1]

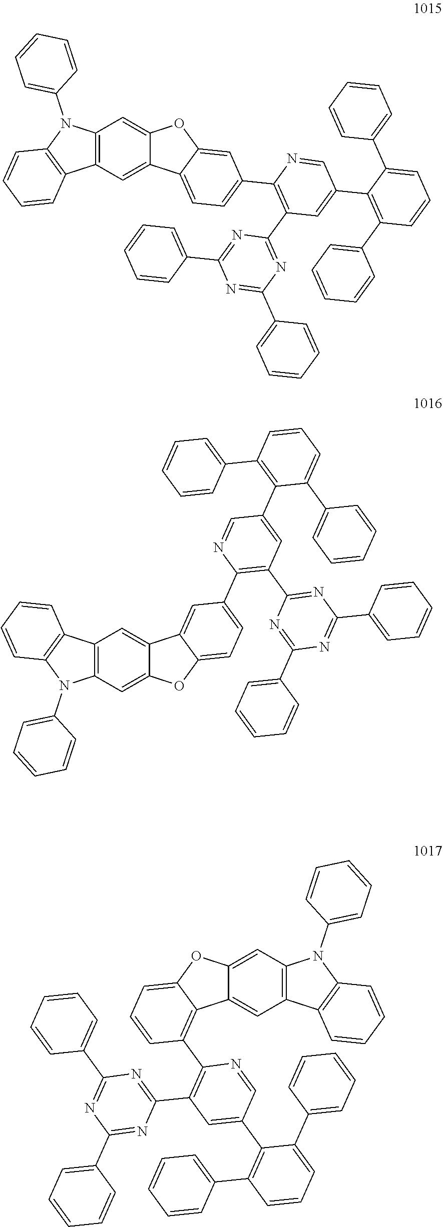 [SMILES: c1ccc(-c2nc(-c3ccccc3)nc(-c3cc(-c4c(-c5ccccc5)cccc4-c4ccccc4)cnc3-c3ccc4c(c3)oc3cc5c(cc34)c3ccccc3n5-c3ccccc3)n2)cc1 ; c1ccc(-c2nc(-c3ccccc3)nc(-c3cc(-c4c(-c5ccccc5)cccc4-c4ccccc4)cnc3-c3ccc4oc5cc6c(cc5c4c3)c3ccccc3n6-c3ccccc3)n2)cc1 ; c1ccc(-c2nc(-c3ccccc3)nc(-c3cc(-c4c(-c5ccccc5)cccc4-c4ccccc4)cnc3-c3cccc4oc5cc6c(cc5c34)c3ccccc3n6-c3ccccc3)n2)cc1]

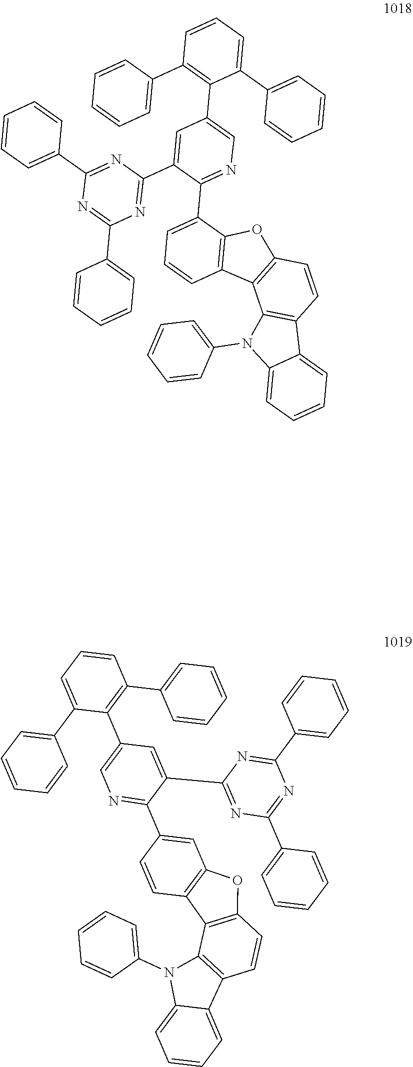 [SMILES: c1ccc(-c2nc(-c3ccccc3)nc(-c3cc(-c4c(-c5ccccc5)cccc4-c4ccccc4)cnc3-c3cccc4c3oc3ccc5c6ccccc6n(-c6ccccc6)c5c34)n2)cc1 ; c1ccc(-c2nc(-c3ccccc3)nc(-c3cc(-c4c(-c5ccccc5)cccc4-c4ccccc4)cnc3-c3ccc4c(c3)oc3ccc5c6ccccc6n(-c6ccccc6)c5c34)n2)cc1]

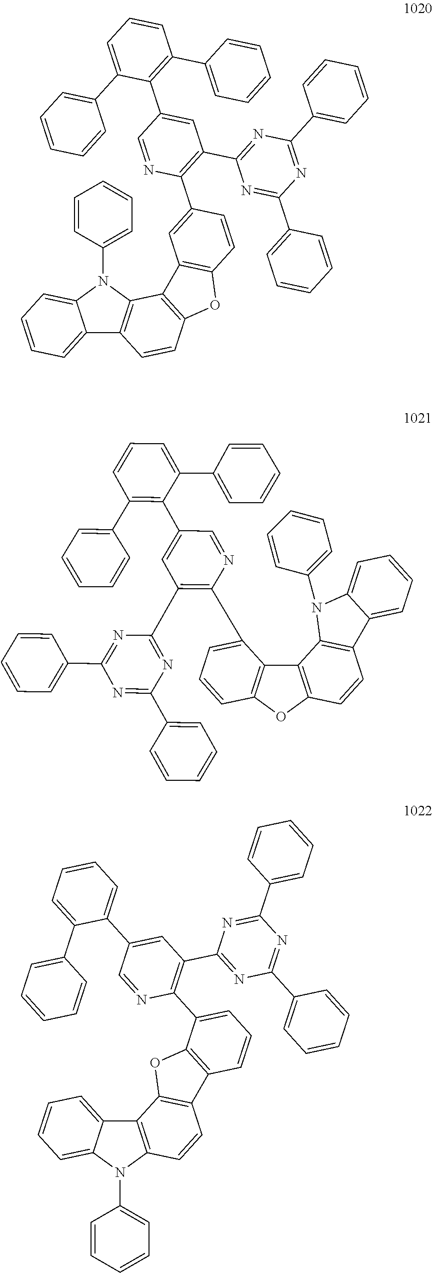 [SMILES: c1ccc(-c2nc(-c3ccccc3)nc(-c3cc(-c4c(-c5ccccc5)cccc4-c4ccccc4)cnc3-c3ccc4oc5ccc6c7ccccc7n(-c7ccccc7)c6c5c4c3)n2)cc1 ; c1ccc(-c2nc(-c3ccccc3)nc(-c3cc(-c4c(-c5ccccc5)cccc4-c4ccccc4)cnc3-c3cccc4oc5ccc6c7ccccc7n(-c7ccccc7)c6c5c34)n2)cc1 ; c1ccc(-c2nc(-c3ccccc3)nc(-c3cc(-c4ccccc4-c4ccccc4)cnc3-c3cccc4c3oc3c4ccc4c3c3ccccc3n4-c3ccccc3)n2)cc1]

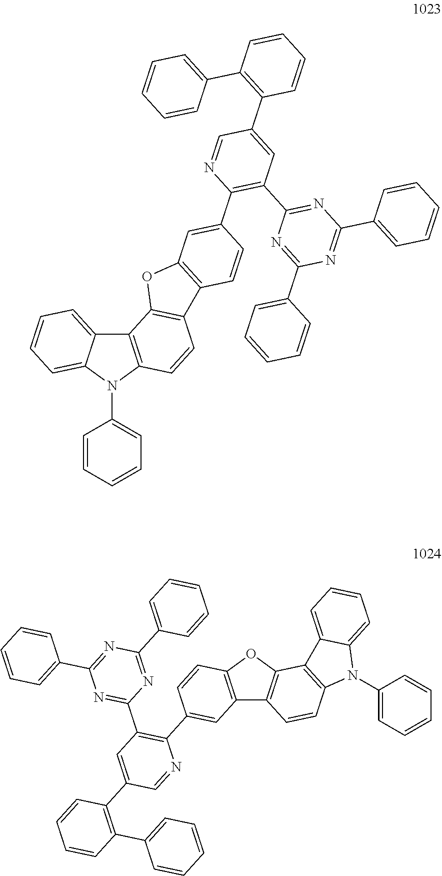 [SMILES: c1ccc(-c2nc(-c3ccccc3)nc(-c3cc(-c4ccccc4-c4ccccc4)cnc3-c3ccc4c(c3)oc3c4ccc4c3c3ccccc3n4-c3ccccc3)n2)cc1 ; c1ccc(-c2nc(-c3ccccc3)nc(-c3cc(-c4ccccc4-c4ccccc4)cnc3-c3ccc4oc5c(ccc6c5c5ccccc5n6-c5ccccc5)c4c3)n2)cc1]

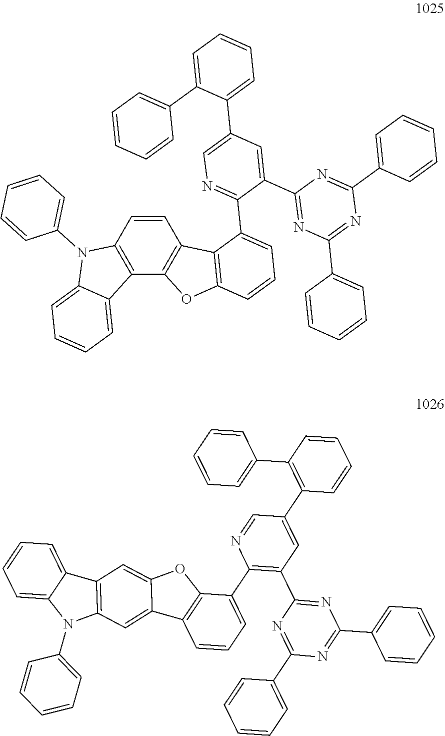 [SMILES: c1ccc(-c2nc(-c3ccccc3)nc(-c3cc(-c4ccccc4-c4ccccc4)cnc3-c3cccc4oc5c(ccc6c5c5ccccc5n6-c5ccccc5)c34)n2)cc1 ; c1ccc(-c2nc(-c3ccccc3)nc(-c3cc(-c4ccccc4-c4ccccc4)cnc3-c3cccc4c3oc3cc5c6ccccc6n(-c6ccccc6)c5cc34)n2)cc1]

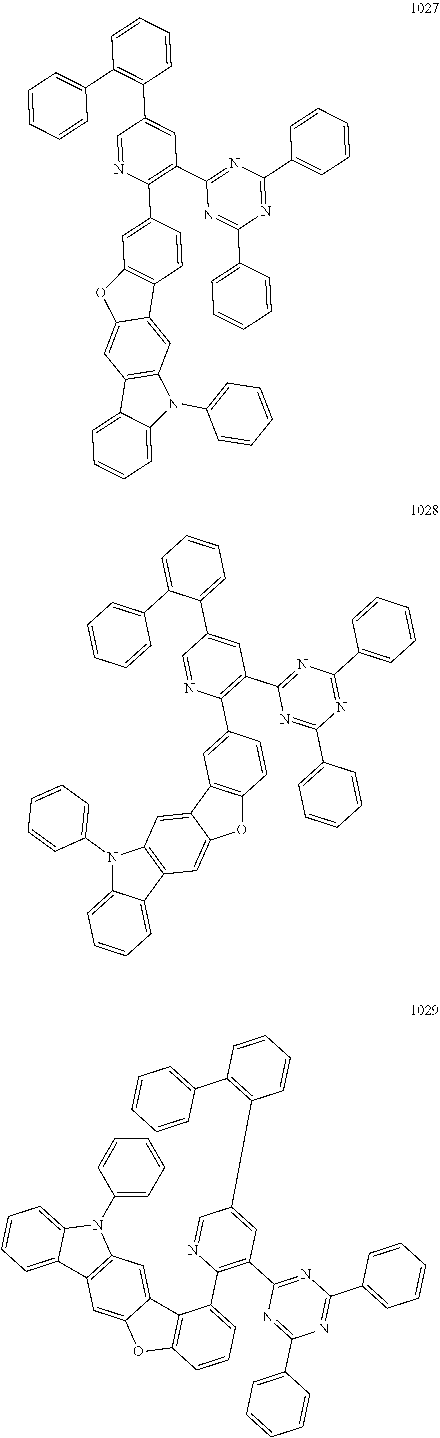 [SMILES: c1ccc(-c2nc(-c3ccccc3)nc(-c3cc(-c4ccccc4-c4ccccc4)cnc3-c3ccc4c(c3)oc3cc5c6ccccc6n(-c6ccccc6)c5cc34)n2)cc1 ; c1ccc(-c2nc(-c3ccccc3)nc(-c3cc(-c4ccccc4-c4ccccc4)cnc3-c3ccc4oc5cc6c7ccccc7n(-c7ccccc7)c6cc5c4c3)n2)cc1 ; c1ccc(-c2nc(-c3ccccc3)nc(-c3cc(-c4ccccc4-c4ccccc4)cnc3-c3cccc4oc5cc6c7ccccc7n(-c7ccccc7)c6cc5c34)n2)cc1]

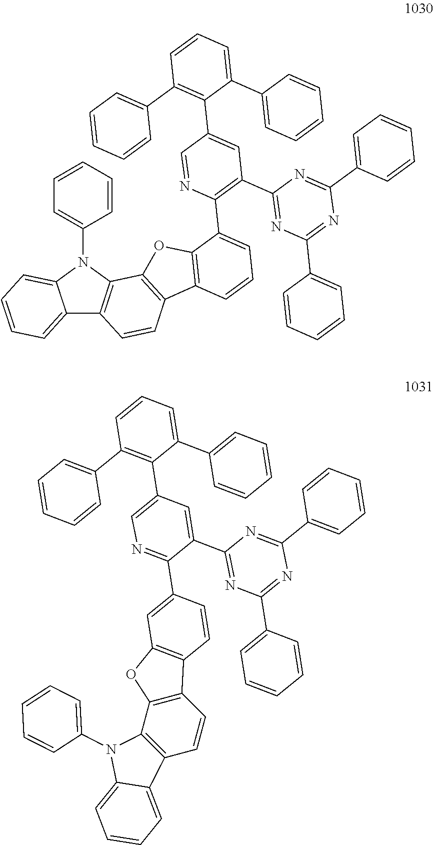 [SMILES: c1ccc(-c2nc(-c3ccccc3)nc(-c3cc(-c4c(-c5ccccc5)cccc4-c4ccccc4)cnc3-c3cccc4c3oc3c4ccc4c5ccccc5n(-c5ccccc5)c43)n2)cc1 ; c1ccc(-c2nc(-c3ccccc3)nc(-c3cc(-c4c(-c5ccccc5)cccc4-c4ccccc4)cnc3-c3ccc4c(c3)oc3c4ccc4c5ccccc5n(-c5ccccc5)c43)n2)cc1]

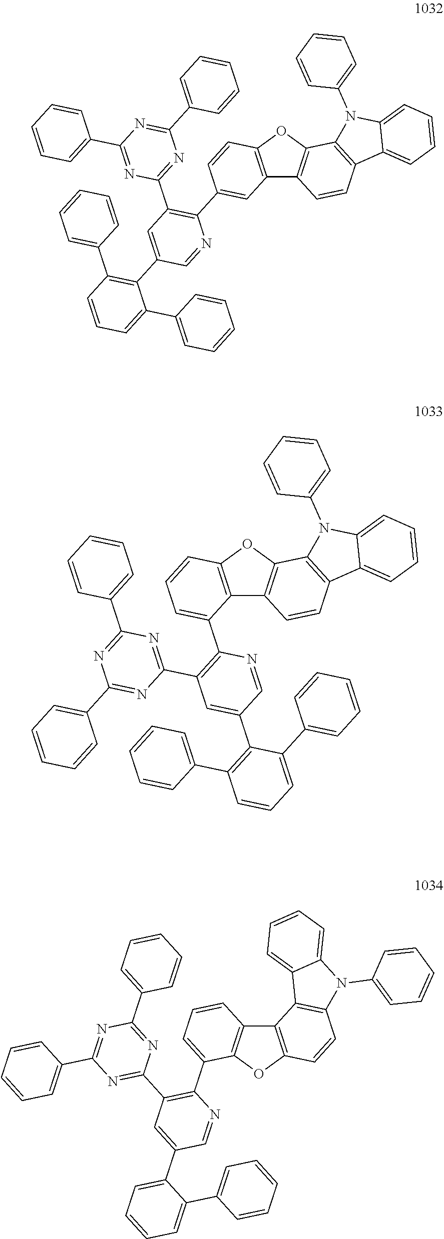 [SMILES: c1ccc(-c2nc(-c3ccccc3)nc(-c3cc(-c4c(-c5ccccc5)cccc4-c4ccccc4)cnc3-c3ccc4oc5c(ccc6c7ccccc7n(-c7ccccc7)c65)c4c3)n2)cc1 ; c1ccc(-c2nc(-c3ccccc3)nc(-c3cc(-c4c(-c5ccccc5)cccc4-c4ccccc4)cnc3-c3cccc4oc5c(ccc6c7ccccc7n(-c7ccccc7)c65)c34)n2)cc1 ; c1ccc(-c2nc(-c3ccccc3)nc(-c3cc(-c4ccccc4-c4ccccc4)cnc3-c3cccc4c3oc3ccc5c(c6ccccc6n5-c5ccccc5)c34)n2)cc1]

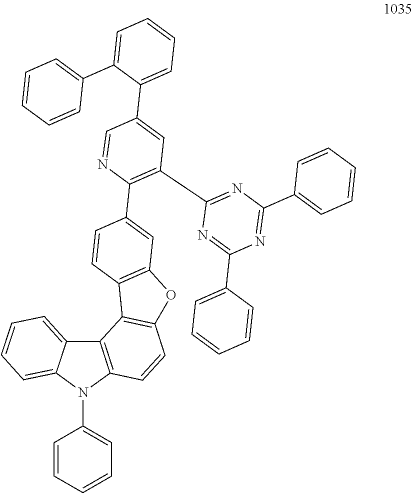 [SMILES: c1ccc(-c2nc(-c3ccccc3)nc(-c3cc(-c4ccccc4-c4ccccc4)cnc3-c3ccc4c(c3)oc3ccc5c(c6ccccc6n5-c5ccccc5)c34)n2)cc1]

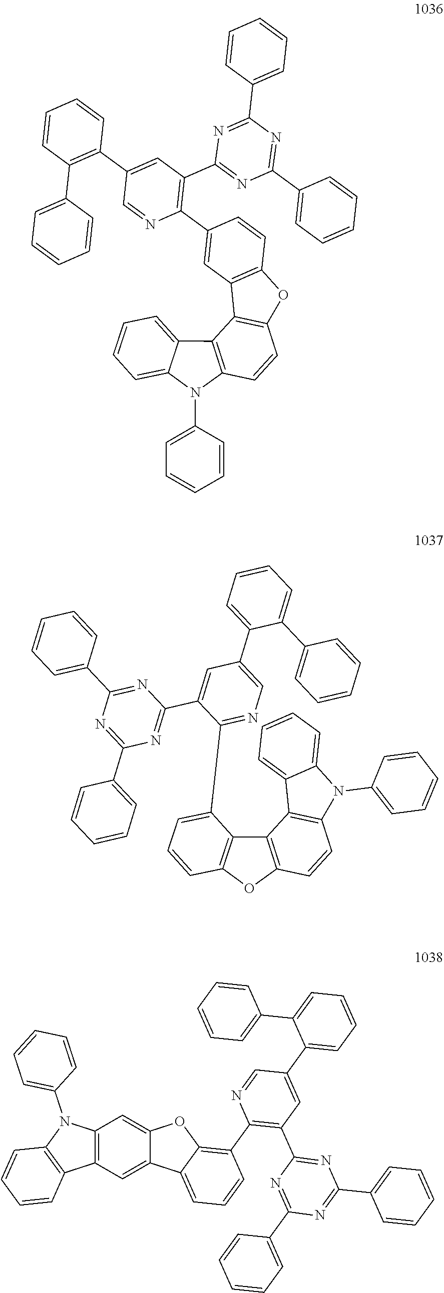 [SMILES: c1ccc(-c2nc(-c3ccccc3)nc(-c3cc(-c4ccccc4-c4ccccc4)cnc3-c3ccc4oc5ccc6c(c7ccccc7n6-c6ccccc6)c5c4c3)n2)cc1 ; c1ccc(-c2nc(-c3ccccc3)nc(-c3cc(-c4ccccc4-c4ccccc4)cnc3-c3cccc4oc5ccc6c(c7ccccc7n6-c6ccccc6)c5c34)n2)cc1 ; c1ccc(-c2nc(-c3ccccc3)nc(-c3cc(-c4ccccc4-c4ccccc4)cnc3-c3cccc4c3oc3cc5c(cc34)c3ccccc3n5-c3ccccc3)n2)cc1]

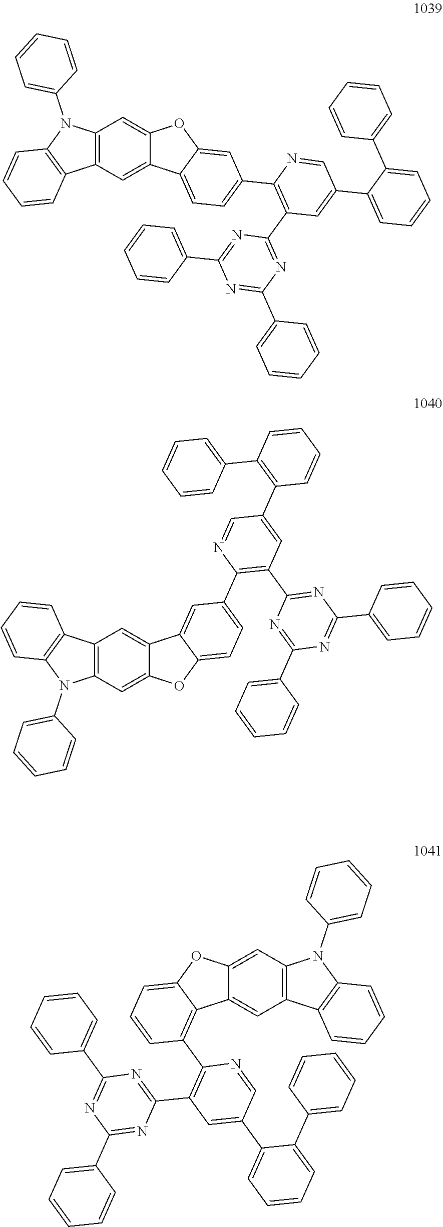 [SMILES: c1ccc(-c2nc(-c3ccccc3)nc(-c3cc(-c4ccccc4-c4ccccc4)cnc3-c3ccc4c(c3)oc3cc5c(cc34)c3ccccc3n5-c3ccccc3)n2)cc1 ; c1ccc(-c2nc(-c3ccccc3)nc(-c3cc(-c4ccccc4-c4ccccc4)cnc3-c3ccc4oc5cc6c(cc5c4c3)c3ccccc3n6-c3ccccc3)n2)cc1 ; c1ccc(-c2nc(-c3ccccc3)nc(-c3cc(-c4ccccc4-c4ccccc4)cnc3-c3cccc4oc5cc6c(cc5c34)c3ccccc3n6-c3ccccc3)n2)cc1]

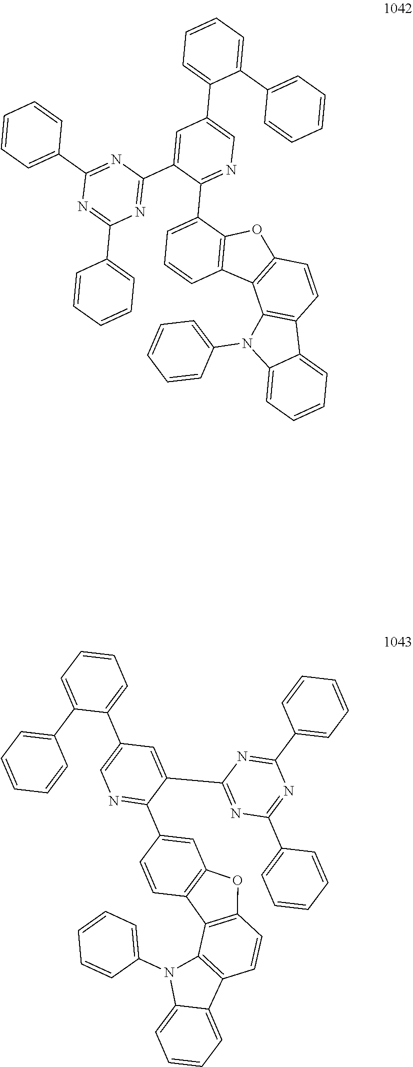 [SMILES: c1ccc(-c2nc(-c3ccccc3)nc(-c3cc(-c4ccccc4-c4ccccc4)cnc3-c3cccc4c3oc3ccc5c6ccccc6n(-c6ccccc6)c5c34)n2)cc1 ; c1ccc(-c2nc(-c3ccccc3)nc(-c3cc(-c4ccccc4-c4ccccc4)cnc3-c3ccc4c(c3)oc3ccc5c6ccccc6n(-c6ccccc6)c5c34)n2)cc1]

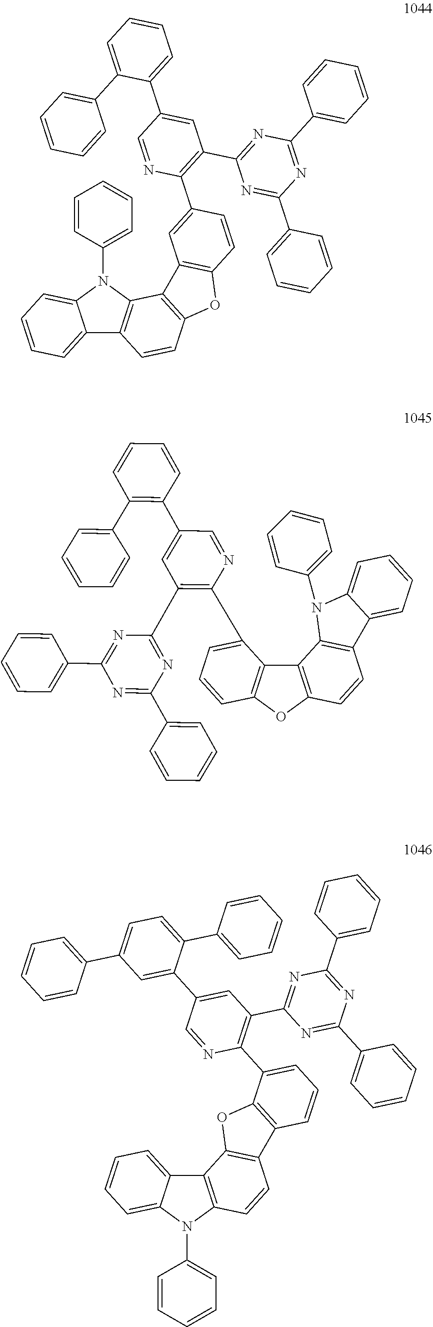 [SMILES: c1ccc(-c2nc(-c3ccccc3)nc(-c3cc(-c4ccccc4-c4ccccc4)cnc3-c3ccc4oc5ccc6c7ccccc7n(-c7ccccc7)c6c5c4c3)n2)cc1 ; c1ccc(-c2nc(-c3ccccc3)nc(-c3cc(-c4ccccc4-c4ccccc4)cnc3-c3cccc4oc5ccc6c7ccccc7n(-c7ccccc7)c6c5c34)n2)cc1 ; c1ccc(-c2ccc(-c3ccccc3)c(-c3cnc(-c4cccc5c4oc4c5ccc5c4c4ccccc4n5-c4ccccc4)c(-c4nc(-c5ccccc5)nc(-c5ccccc5)n4)c3)c2)cc1]

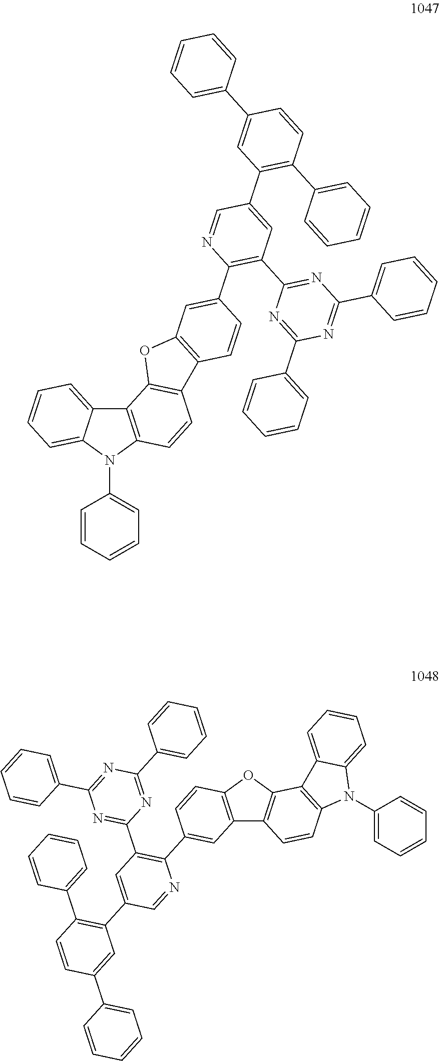 [SMILES: c1ccc(-c2ccc(-c3ccccc3)c(-c3cnc(-c4ccc5c(c4)oc4c5ccc5c4c4ccccc4n5-c4ccccc4)c(-c4nc(-c5ccccc5)nc(-c5ccccc5)n4)c3)c2)cc1 ; c1ccc(-c2ccc(-c3ccccc3)c(-c3cnc(-c4ccc5oc6c(ccc7c6c6ccccc6n7-c6ccccc6)c5c4)c(-c4nc(-c5ccccc5)nc(-c5ccccc5)n4)c3)c2)cc1]

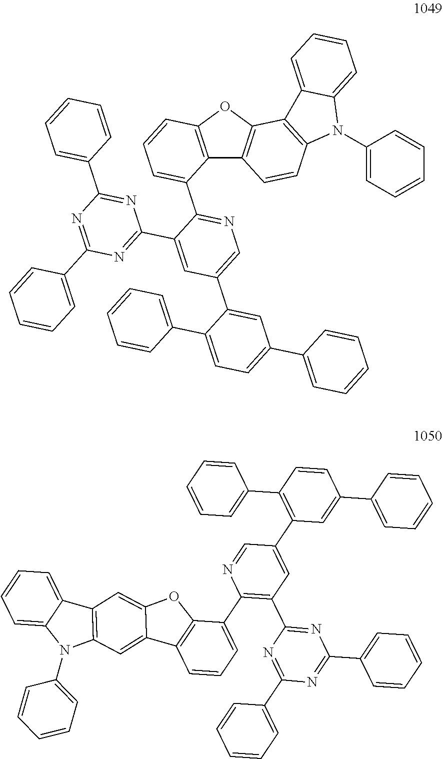 [SMILES: c1ccc(-c2ccc(-c3ccccc3)c(-c3cnc(-c4cccc5oc6c(ccc7c6c6ccccc6n7-c6ccccc6)c45)c(-c4nc(-c5ccccc5)nc(-c5ccccc5)n4)c3)c2)cc1 ; c1ccc(-c2ccc(-c3ccccc3)c(-c3cnc(-c4cccc5c4oc4cc6c7ccccc7n(-c7ccccc7)c6cc45)c(-c4nc(-c5ccccc5)nc(-c5ccccc5)n4)c3)c2)cc1]

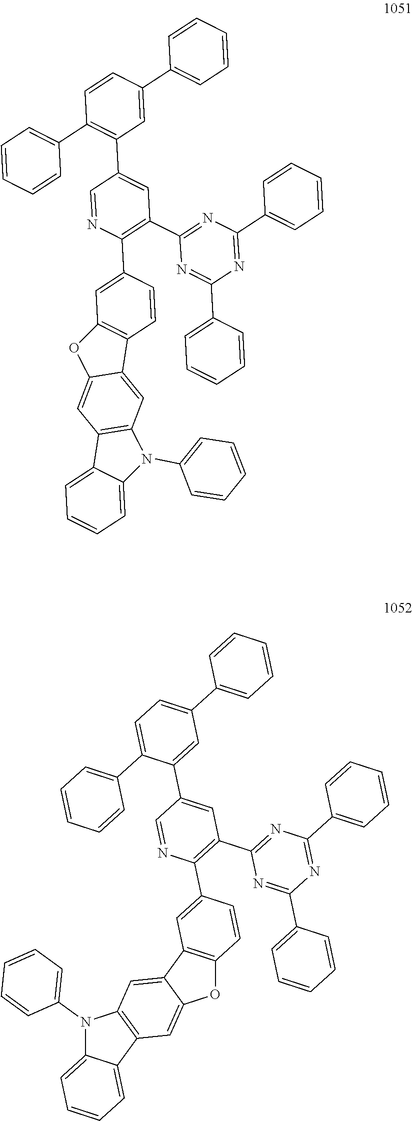 [SMILES: c1ccc(-c2ccc(-c3ccccc3)c(-c3cnc(-c4ccc5c(c4)oc4cc6c7ccccc7n(-c7ccccc7)c6cc45)c(-c4nc(-c5ccccc5)nc(-c5ccccc5)n4)c3)c2)cc1 ; c1ccc(-c2ccc(-c3ccccc3)c(-c3cnc(-c4ccc5oc6cc7c8ccccc8n(-c8ccccc8)c7cc6c5c4)c(-c4nc(-c5ccccc5)nc(-c5ccccc5)n4)c3)c2)cc1]

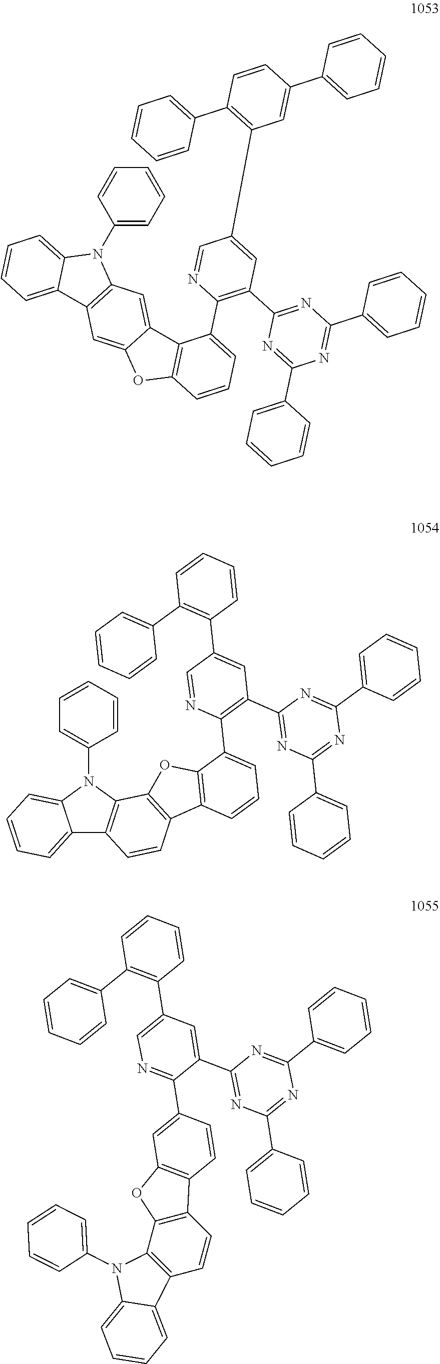 [SMILES: c1ccc(-c2ccc(-c3ccccc3)c(-c3cnc(-c4cccc5oc6cc7c8ccccc8n(-c8ccccc8)c7cc6c45)c(-c4nc(-c5ccccc5)nc(-c5ccccc5)n4)c3)c2)cc1 ; c1ccc(-c2nc(-c3ccccc3)nc(-c3cc(-c4ccccc4-c4ccccc4)cnc3-c3cccc4c3oc3c4ccc4c5ccccc5n(-c5ccccc5)c43)n2)cc1 ; c1ccc(-c2nc(-c3ccccc3)nc(-c3cc(-c4ccccc4-c4ccccc4)cnc3-c3ccc4c(c3)oc3c4ccc4c5ccccc5n(-c5ccccc5)c43)n2)cc1]

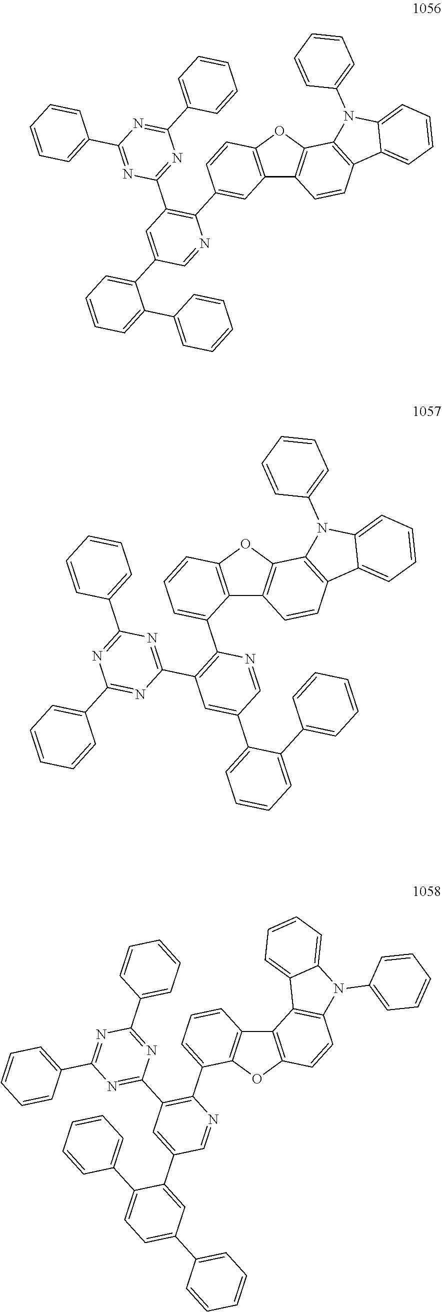 [SMILES: c1ccc(-c2nc(-c3ccccc3)nc(-c3cc(-c4ccccc4-c4ccccc4)cnc3-c3ccc4oc5c(ccc6c7ccccc7n(-c7ccccc7)c65)c4c3)n2)cc1 ; c1ccc(-c2nc(-c3ccccc3)nc(-c3cc(-c4ccccc4-c4ccccc4)cnc3-c3cccc4oc5c(ccc6c7ccccc7n(-c7ccccc7)c65)c34)n2)cc1 ; c1ccc(-c2ccc(-c3ccccc3)c(-c3cnc(-c4cccc5c4oc4ccc6c(c7ccccc7n6-c6ccccc6)c45)c(-c4nc(-c5ccccc5)nc(-c5ccccc5)n4)c3)c2)cc1]

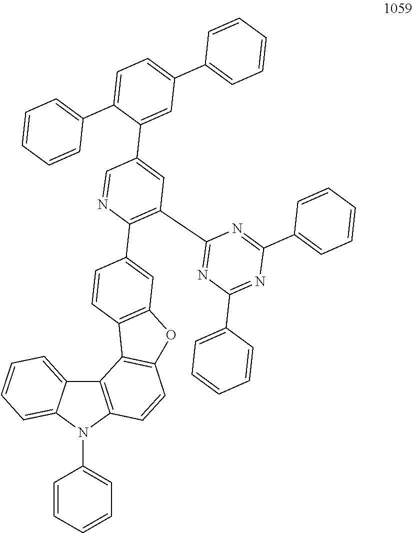 [SMILES: c1ccc(-c2ccc(-c3ccccc3)c(-c3cnc(-c4ccc5c(c4)oc4ccc6c(c7ccccc7n6-c6ccccc6)c45)c(-c4nc(-c5ccccc5)nc(-c5ccccc5)n4)c3)c2)cc1]

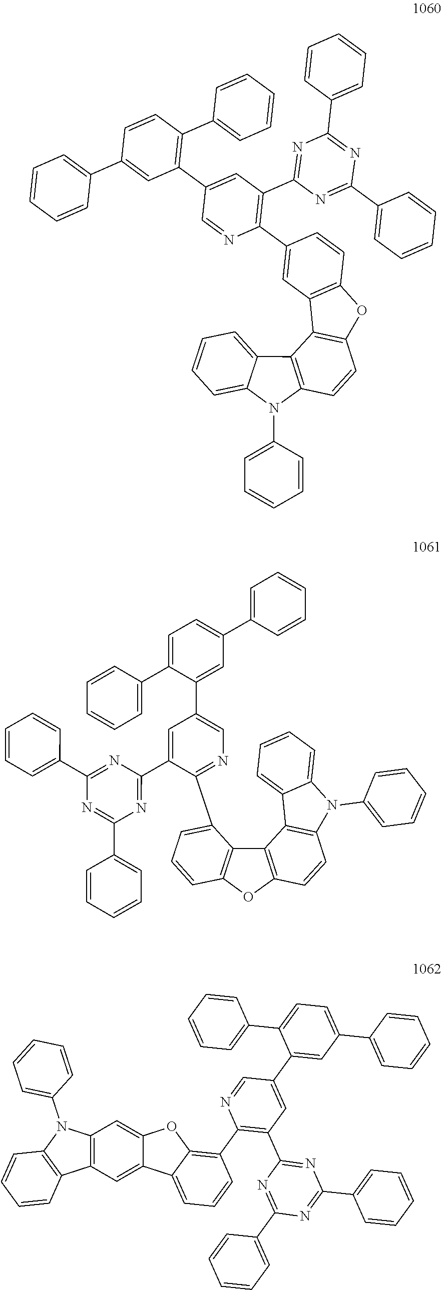 [SMILES: c1ccc(-c2ccc(-c3ccccc3)c(-c3cnc(-c4ccc5oc6ccc7c(c8ccccc8n7-c7ccccc7)c6c5c4)c(-c4nc(-c5ccccc5)nc(-c5ccccc5)n4)c3)c2)cc1 ; c1ccc(-c2ccc(-c3ccccc3)c(-c3cnc(-c4cccc5oc6ccc7c(c8ccccc8n7-c7ccccc7)c6c45)c(-c4nc(-c5ccccc5)nc(-c5ccccc5)n4)c3)c2)cc1 ; c1ccc(-c2ccc(-c3ccccc3)c(-c3cnc(-c4cccc5c4oc4cc6c(cc45)c4ccccc4n6-c4ccccc4)c(-c4nc(-c5ccccc5)nc(-c5ccccc5)n4)c3)c2)cc1]

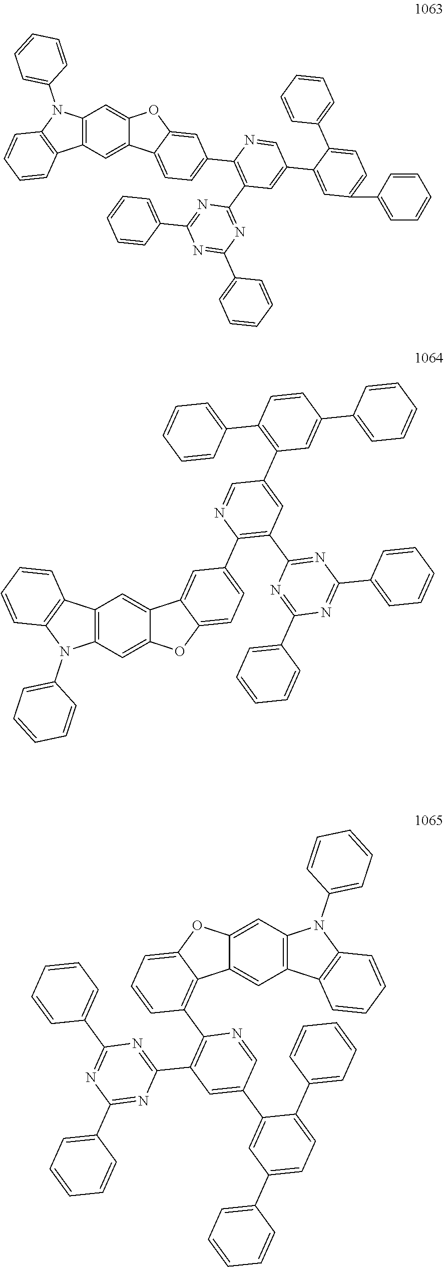 [SMILES: c1ccc(-c2ccc(-c3ccccc3)c(-c3cnc(-c4ccc5c(c4)oc4cc6c(cc45)c4ccccc4n6-c4ccccc4)c(-c4nc(-c5ccccc5)nc(-c5ccccc5)n4)c3)c2)cc1 ; c1ccc(-c2ccc(-c3ccccc3)c(-c3cnc(-c4ccc5oc6cc7c(cc6c5c4)c4ccccc4n7-c4ccccc4)c(-c4nc(-c5ccccc5)nc(-c5ccccc5)n4)c3)c2)cc1 ; c1ccc(-c2ccc(-c3ccccc3)c(-c3cnc(-c4cccc5oc6cc7c(cc6c45)c4ccccc4n7-c4ccccc4)c(-c4nc(-c5ccccc5)nc(-c5ccccc5)n4)c3)c2)cc1]

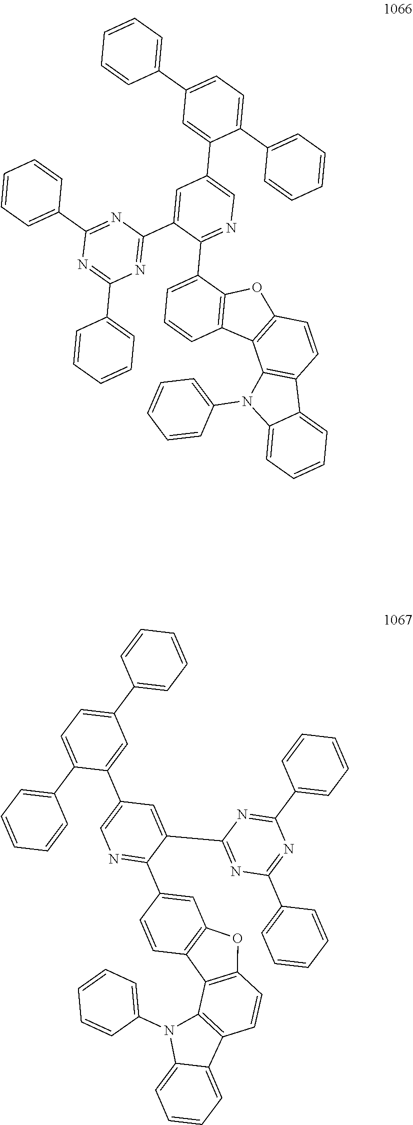 [SMILES: c1ccc(-c2ccc(-c3ccccc3)c(-c3cnc(-c4cccc5c4oc4ccc6c7ccccc7n(-c7ccccc7)c6c45)c(-c4nc(-c5ccccc5)nc(-c5ccccc5)n4)c3)c2)cc1 ; c1ccc(-c2ccc(-c3ccccc3)c(-c3cnc(-c4ccc5c(c4)oc4ccc6c7ccccc7n(-c7ccccc7)c6c45)c(-c4nc(-c5ccccc5)nc(-c5ccccc5)n4)c3)c2)cc1]

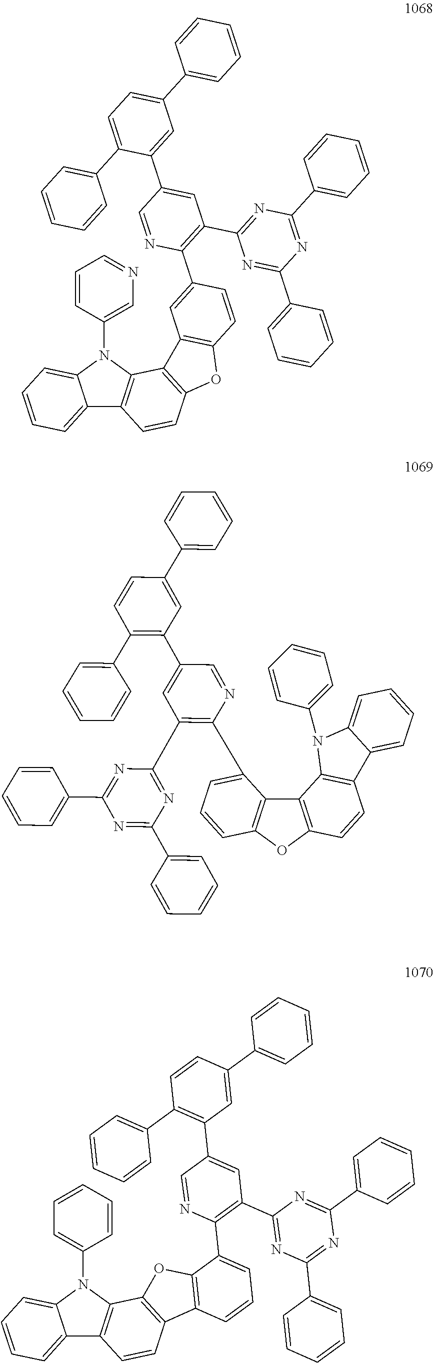 [SMILES: c1ccc(-c2ccc(-c3ccccc3)c(-c3cnc(-c4ccc5oc6ccc7c8ccccc8n(-c8cccnc8)c7c6c5c4)c(-c4nc(-c5ccccc5)nc(-c5ccccc5)n4)c3)c2)cc1 ; c1ccc(-c2ccc(-c3ccccc3)c(-c3cnc(-c4cccc5oc6ccc7c8ccccc8n(-c8ccccc8)c7c6c45)c(-c4nc(-c5ccccc5)nc(-c5ccccc5)n4)c3)c2)cc1 ; c1ccc(-c2ccc(-c3ccccc3)c(-c3cnc(-c4cccc5c4oc4c5ccc5c6ccccc6n(-c6ccccc6)c54)c(-c4nc(-c5ccccc5)nc(-c5ccccc5)n4)c3)c2)cc1]

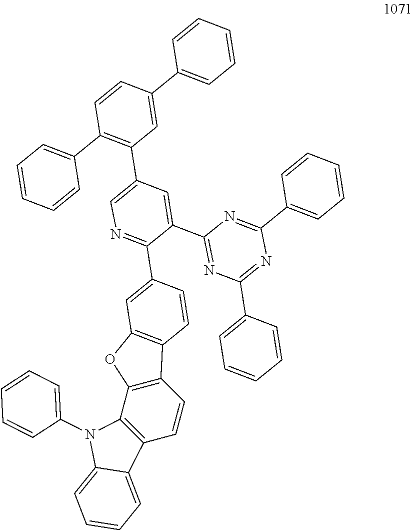 [SMILES: c1ccc(-c2ccc(-c3ccccc3)c(-c3cnc(-c4ccc5c(c4)oc4c5ccc5c6ccccc6n(-c6ccccc6)c54)c(-c4nc(-c5ccccc5)nc(-c5ccccc5)n4)c3)c2)cc1]

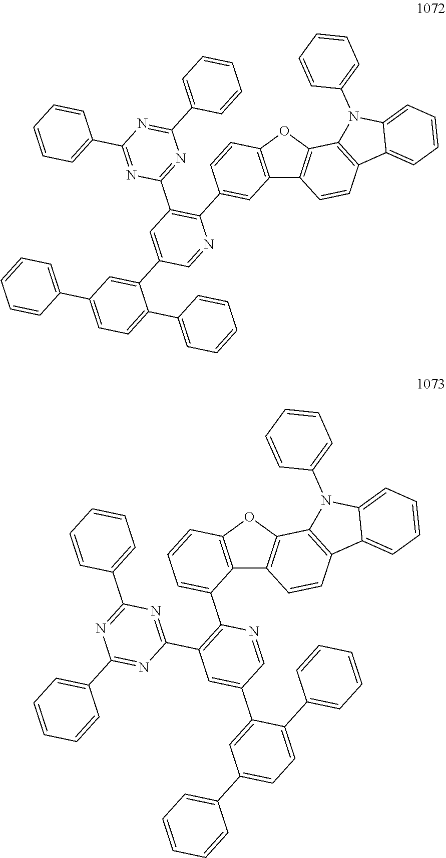 [SMILES: c1ccc(-c2ccc(-c3ccccc3)c(-c3cnc(-c4ccc5oc6c(ccc7c8ccccc8n(-c8ccccc8)c76)c5c4)c(-c4nc(-c5ccccc5)nc(-c5ccccc5)n4)c3)c2)cc1 ; c1ccc(-c2ccc(-c3ccccc3)c(-c3cnc(-c4cccc5oc6c(ccc7c8ccccc8n(-c8ccccc8)c76)c45)c(-c4nc(-c5ccccc5)nc(-c5ccccc5)n4)c3)c2)cc1]

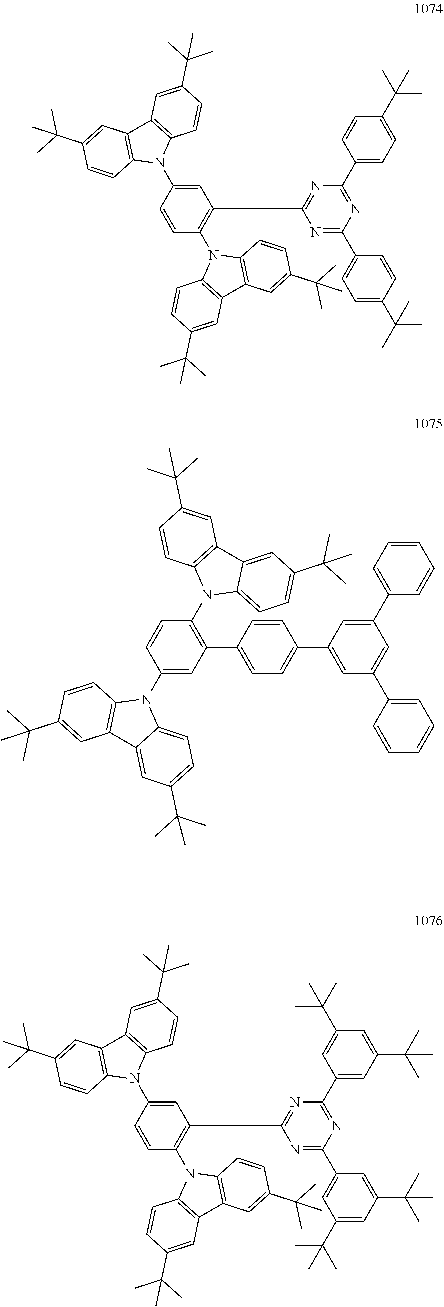

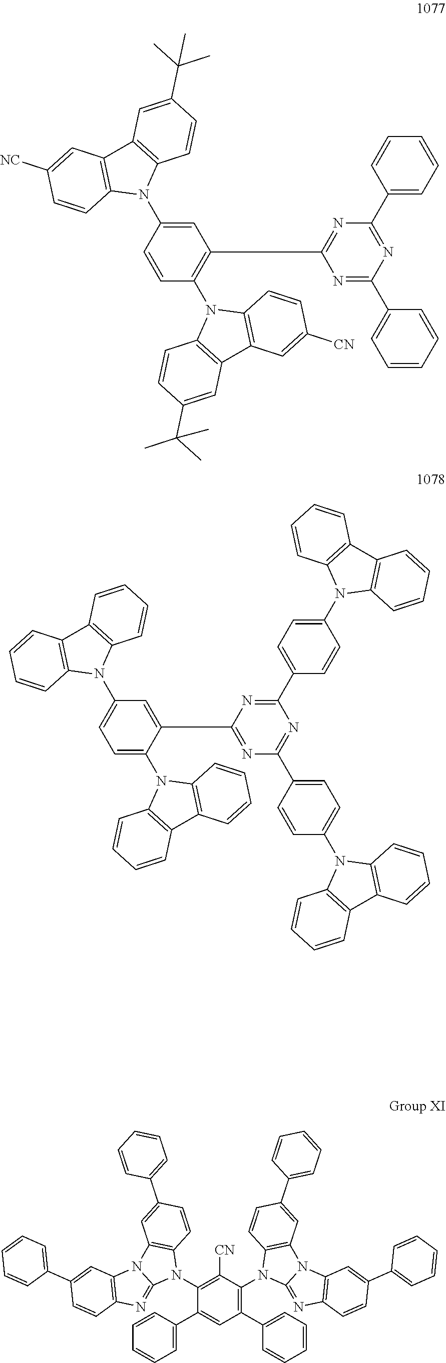 [SMILES: CC(C)(C)c1ccc2c(c1)c1cc(C#N)ccc1n2-c1ccc(-n2c3ccc(C#N)cc3c3cc(C(C)(C)C)ccc32)c(-c2nc(-c3ccccc3)nc(-c3ccccc3)n2)c1 ; c1ccc2c(c1)c1ccccc1n2-c1ccc(-c2nc(-c3ccc(-n4c5ccccc5c5ccccc54)cc3)nc(-c3cc(-n4c5ccccc5c5ccccc54)ccc3-n3c4ccccc4c4ccccc43)n2)cc1 ; N#Cc1c(-n2c3ccc(-c4ccccc4)cc3n3c4cc(-c5ccccc5)ccc4nc23)c(-c2ccccc2)cc(-c2ccccc2)c1-n1c2ccc(-c3ccccc3)cc2n2c3cc(-c4ccccc4)ccc3nc12]

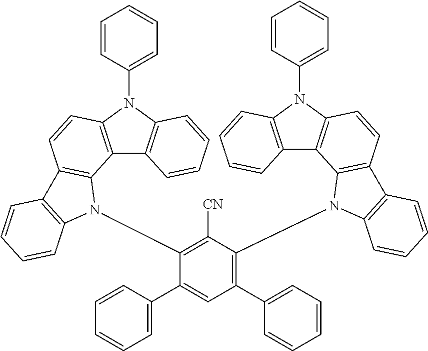 [SMILES: N#Cc1c(-n2c3ccccc3c3ccc4c(c5ccccc5n4-c4ccccc4)c32)c(-c2ccccc2)cc(-c2ccccc2)c1-n1c2ccccc2c2ccc3c(c4ccccc4n3-c3ccccc3)c21]

### Electron Transport Region 17

Then, an electron transport region may be located on the emission layer.

The electron transport region 17 is placed between the emission layer 15 and the second electrode 19 of the organic light-emitting device 10.

The electron transport region 17 may have a single-layered structure or a multi-layered structure.

For example, the electron transport region 17 may have an electron transport layer, an electron transport layer/electron injection layer structure, a buffer layer/electron transport layer structure, hole blocking layer/electron transport layer structure, a buffer layer/electron transport layer/electron injection layer structure, or a hole blocking layer/electron transport layer/electron injection layer structure, but embodiments of the present disclosure are not limited thereto. The electron transport region 17 may further include an electron control layer.

The electron transport region 17 may include known electron transport materials.

The electron transport region (for example, a buffer layer, a hole blocking layer, an electron control layer, or an electron transport layer in the electron transport region) may include a metal-free compound containing at least one π electron-deficient nitrogen-containing C₁-C₆₀ cyclic group. The π electron-deficient nitrogen-containing C₁-C₆₀ cyclic group is the same as described above.

In one or more embodiments, the electron transport region may include a compound represented by Formula 601 below:

[Ar₆₀₁]ₓₑ₁₁-[(L₆₀₁)ₓₑ₁-R₆₀₁]ₓₑ₂₁ Formula 601

wherein, in Formula 601,

Ar₆₀₁ and L₆₀₁ may each independently be a C₅-C₆₀ carbocyclic group unsubstituted or substituted with at least one R₆₀₁ₐ or a C₁-C₆₀ heterocyclic group unsubstituted or substituted with at least one R₆₀₁ₐ,

xe11 may be 1, 2, or 3,

xe1 may be an integer from 0 to 5,

R₆₀₁ₐ and R₆₀₁ may each independently be a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted C₁-C₆₀ heteroaryloxy group, a substituted or unsubstituted C₁-C₆₀ heteroarylthio group, a substituted or unsubstituted C₂-C₆₀ heteroarylalkyl group, a substituted or unsubstituted monovalent non-aromatic condensed polycyclic group, a substituted or unsubstituted monovalent non-aromatic condensed heteropolycyclic group, —Si(Q₆₀₁)(Q₆₀₂)(Q₆₀₃), —C(═O)(Q₆₀₁), —S(═O)₂(Q₆₀₁), or —P(═O)(Q₆₀₁)(Q₆₀₂),

Q₆₀₁ to Q₆₀₃ may each independently be a C₁-C₁₀ alkyl group, a C₁-C₁₀ alkoxy group, a phenyl group, a biphenyl group, a terphenyl group, or a naphthyl group, and

xe21 may be an integer from 1 to 5.

In one or more embodiments, at least one of Ar₆₀₁(s) in the number of xe11 and R₆₀₁(s) in the number of xe21 may include the π electron-deficient nitrogen-containing C₁-C₆₀ cyclic group.

In one or more embodiments. Ar₆₀₁ and L₆₀₁ in Formula 601 may each independently be a benzene group, a naphthalene group, a fluorene group, a spiro-bifluorene group, a benzofluorene group, a dibenzofluorene group, a phenalene group, a phenanthrene group, an anthracene group, a fluoranthene group, a triphenylene group, a pyrene group, a chrysene group, a naphthacene group, a picene group, a perylene group, a pentaphene group, an indenoanthracene group, a dibenzofuran group, a dibenzothiophene group, a carbazole group, an imidazole group, a pyrazole group, a thiazole group, an isothiazole group, an oxazole group, an isoxazole group, a pyridine group, a pyrazine group, a pyrimidine group, a pyridazine group, an indazole group, a purine group, a quinoline group, an isoquinoline group, a benzoquinoline group, a phthalazine group, a naphthyridine group, a quinoxaline group, a quinazoline group, a cinnoline group, a phenanthridine group, an acrdine group, a phenanthroline group, a phenazine group, a benzimidazole group, an isobenzothiazole group, a benzoxazole group, an isobenzoxazole group, a triazole group, a tetrazole group, an oxadiazole group, a triazine group, a thiadiazole group, an imidazopyridine group, an imidazopyrimidine group, or an azacarbazole group, each unsubstituted or substituted with at least one of deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a phenyl group, a biphenyl group, a terphenyl group, a naphthyl group, —Si(Q₃₁)(Q₃₂)(Q₃₃), —S(═O)₂(Q₃₁), or —P(═O)(Q₃₁)(Q₃₂), and

Q₃₁ to Q₃₃ may each independently be a C₁-C₁₀ alkyl group, a C₁-C₁₀ alkoxy group, a phenyl group, a biphenyl group, a terphenyl group, or a naphthyl group.

When xe11 in Formula 601 is 2 or more, two or more Ar₆₀₁(s) may be linked to each other via a single bond.

In one or more embodiments, Ar₆₀₁ in Formula 601 may be an anthracene group.

In one or more embodiments, the compound represented by Formula 601 may be represented by Formula 601-1:

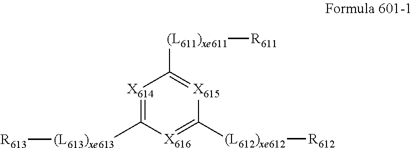

In Formula 601-1,

X₆₁₄ may be N or C(R₆₁₄), X₆₁₅ may be N or C(R₆₁₅), X₆₁₆ may be N or C(R₆₁₆), at least one of X₆₁₄ to X₆₁₆ may be N,

L₆₁₁ to L₆₁₃ may each independently be the same as described in connection with L₆₀₁,

xe611 to xe613 may each independently be the same as described in connection with xe1,

R₆₁₁ to R₆₁₃ may each independently be the same as described in connection with R₆₀₁, and

R₆₁₄ to R₆₁₆ may each independently be hydrogen, deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a phenyl group, a biphenyl group, a terphenyl group, or a naphthyl group.

In one or more embodiments, xe1 and xe611 to xe613 in Formulae 601 and 601-1 may each independently be 0, 1, or 2.

In one or more embodiments, R₆₀₁ and R₆₁₁ to R₆₁₃ in Formulae 601 and 601-1 may each independently be a phenyl group, a biphenyl group, a terphenyl group, a naphthyl group, a fluorenyl group, a spiro-bifluorenyl group, a benzofluorenyl group, a dibenzofluorenyl group, a phenanthrenyl group, an anthracenyl group, a fluoranthenyl group, a triphenylenyl group, a pyrenyl group, a chrysenyl group, a perylenyl group, a pentaphenyl group, a hexacenyl group, a pentacenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, a pyridinyl group, an imidazolyl group, a pyrazolyl group, a thiazolyl group, an isothiazolyl group, an oxazolyl group, an isoxazolyl group, a thiadiazolyl group, an oxadiazolyl group, a pyrazinyl group, a pyrimidinyl group, a pyridazinyl group, a triazinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a phenanthridinyl group, an acridinyl group, a phenanthrolinyl group, a phenazinyl group, a benzimidazolyl group, an isobenzothiazolyl group, a benzoxazolyl group, an isobenzoxazolyl group, a triazolyl group, a tetrazolyl group, an imidazopyridinyl group, an imidazopyrimidinyl group, or an azacarbazolyl group, each unsubstituted or substituted with deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a phenyl group, a biphenyl group, a terphenyl group, a naphthyl group, a fluorenyl group, a spiro-bifluorenyl group, a benzofluorenyl group, a dibenzofluorenyl group, a phenanthrenyl group, an anthracenyl group, a fluoranthenyl group, a triphenylenyl group, a pyrenyl group, a chrysenyl group, a perylenyl group, a pentaphenyl group, a hexacenyl group, a pentacenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, a pyridinyl group, an imidazolyl group, a pyrazolyl group, a thiazolyl group, an isothiazolyl group, an oxazolyl group, an isoxazolyl group, a thiadiazolyl group, an oxadiazolyl group, a pyrazinyl group, a pyrimidinyl group, a pyridazinyl group, a triazinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a phenanthridinyl group, an acridinyl group, a phenanthrolinyl group, a phenazinyl group, a benzimidazolyl group, an isobenzothiazolyl group, a benzoxazolyl group, an isobenzoxazolyl group, a triazolyl group, a tetrazolyl group, an imidazopyridinyl group, an imidazopyrimidinyl group, or an azacarbazolyl group; or

—S(═O)₂(Q₆₀₁), or —P(═O)(Q₆₀₁)(Q₆₀₂),

wherein Q₆₀₁ and Q₆₀₂ are the same as described above.

The electron transport region may include at least one of Compounds ET1 to ET36, but embodiments of the present disclosure are not limited thereto:

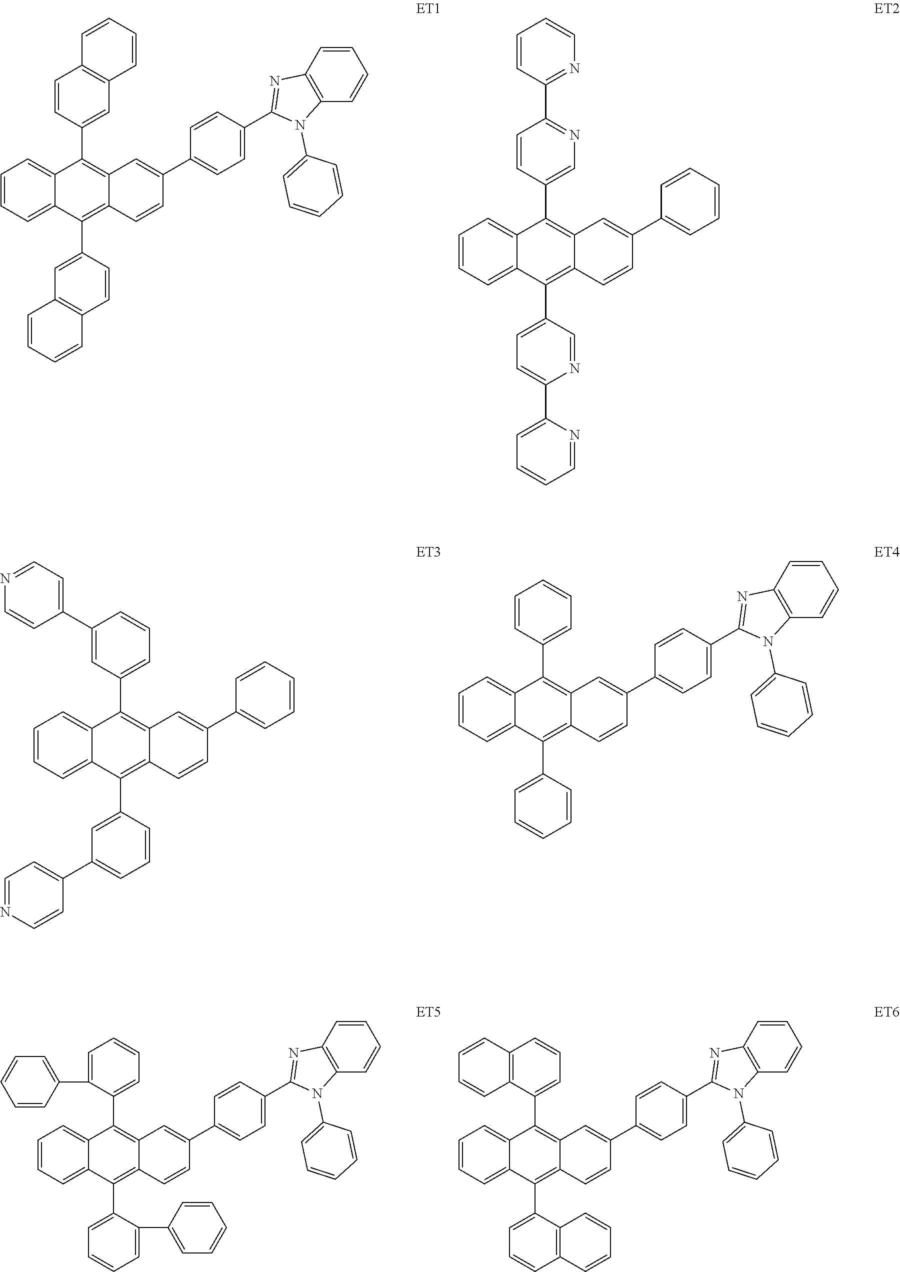

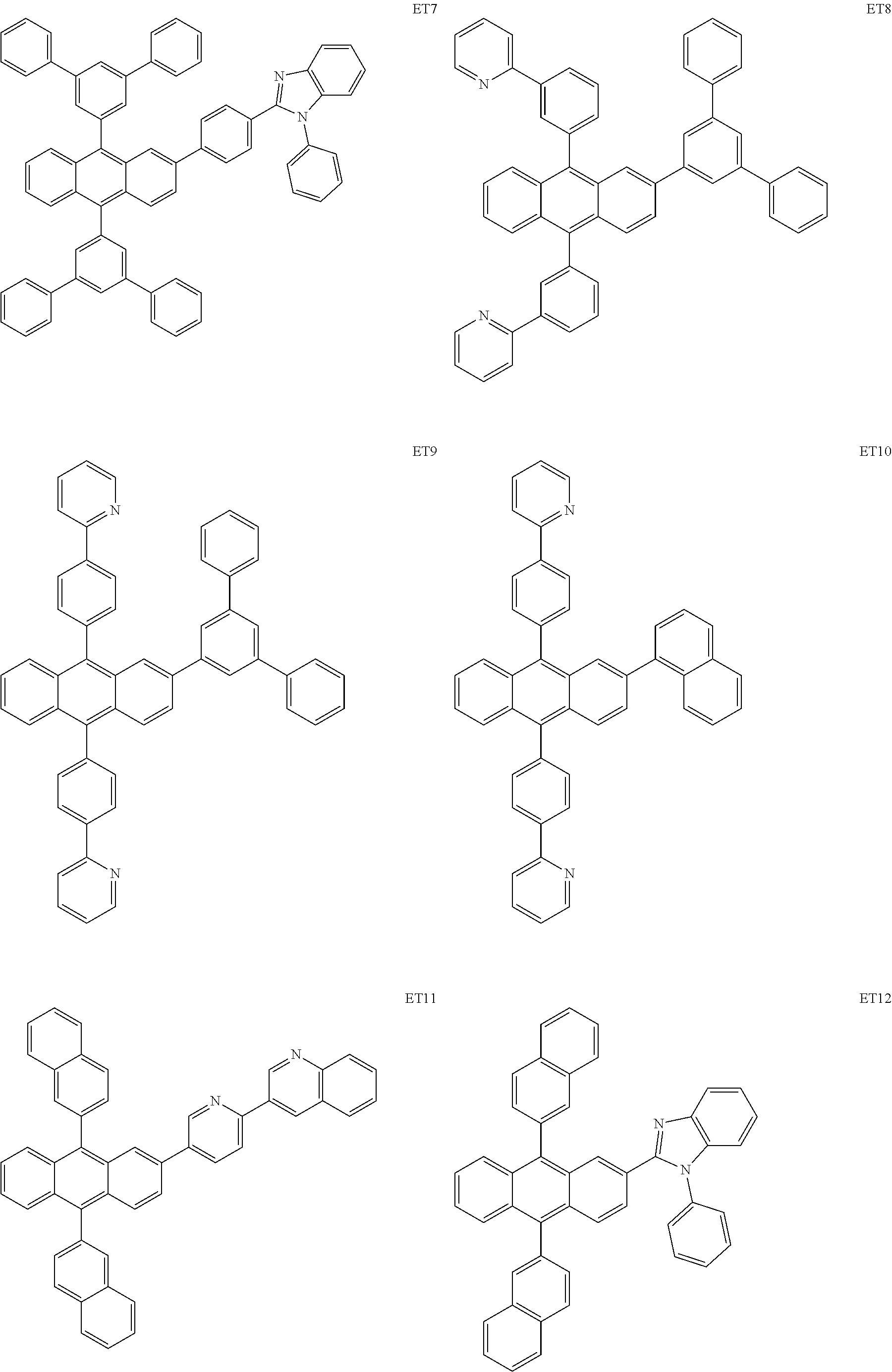

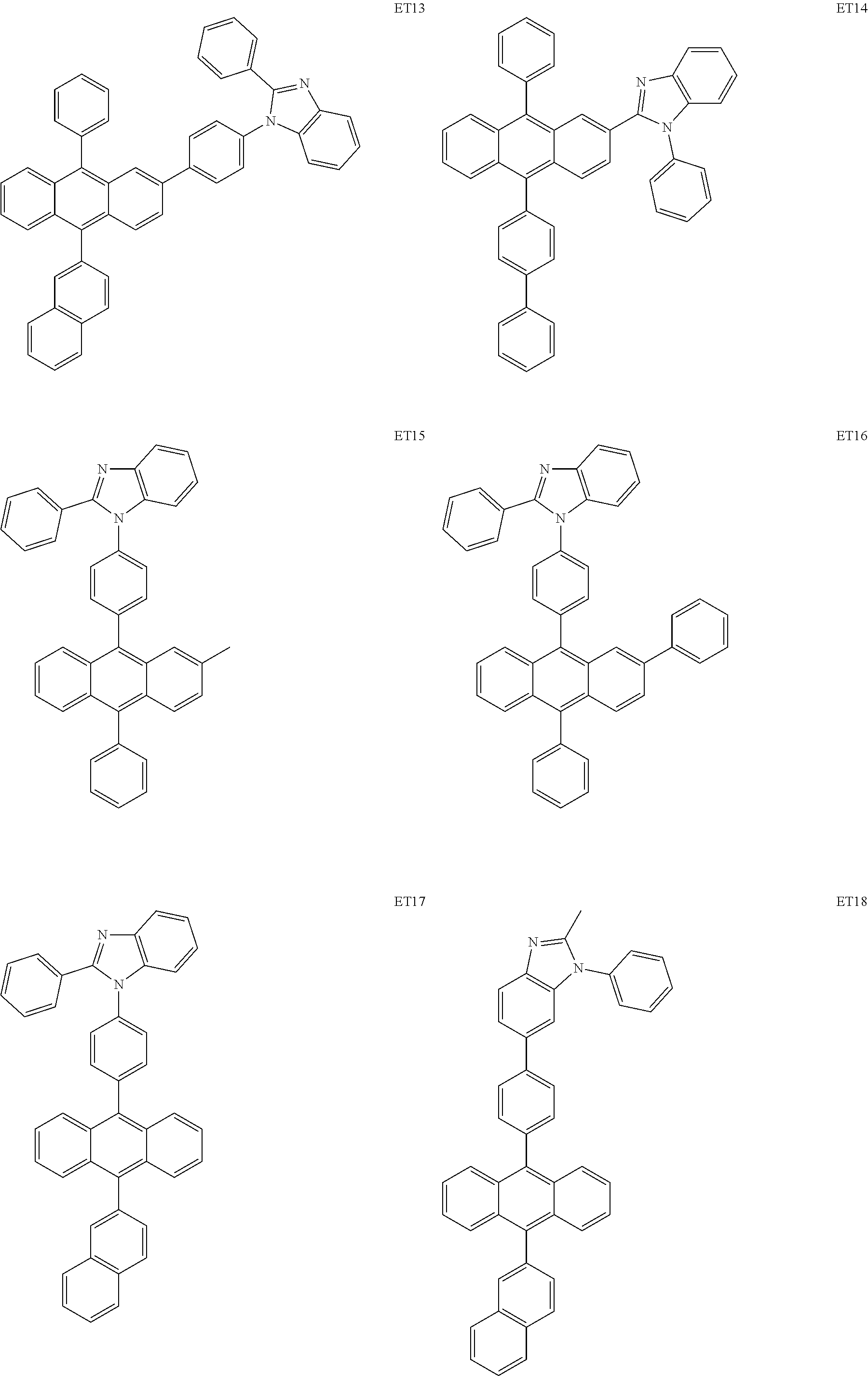 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1 ; c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccc6ccccc6c5)c5ccccc45)cc3)cc2n1-c1ccccc1]

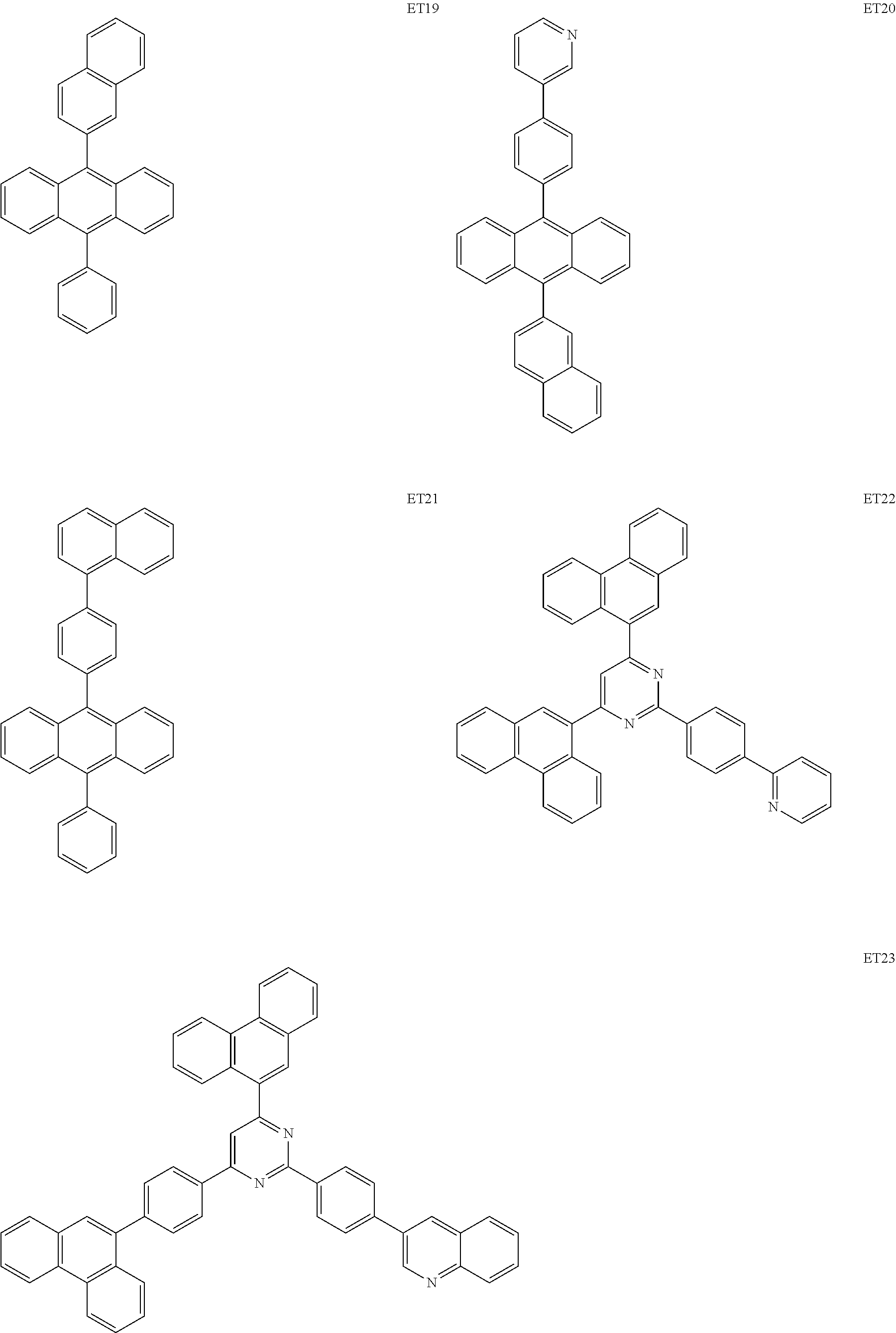

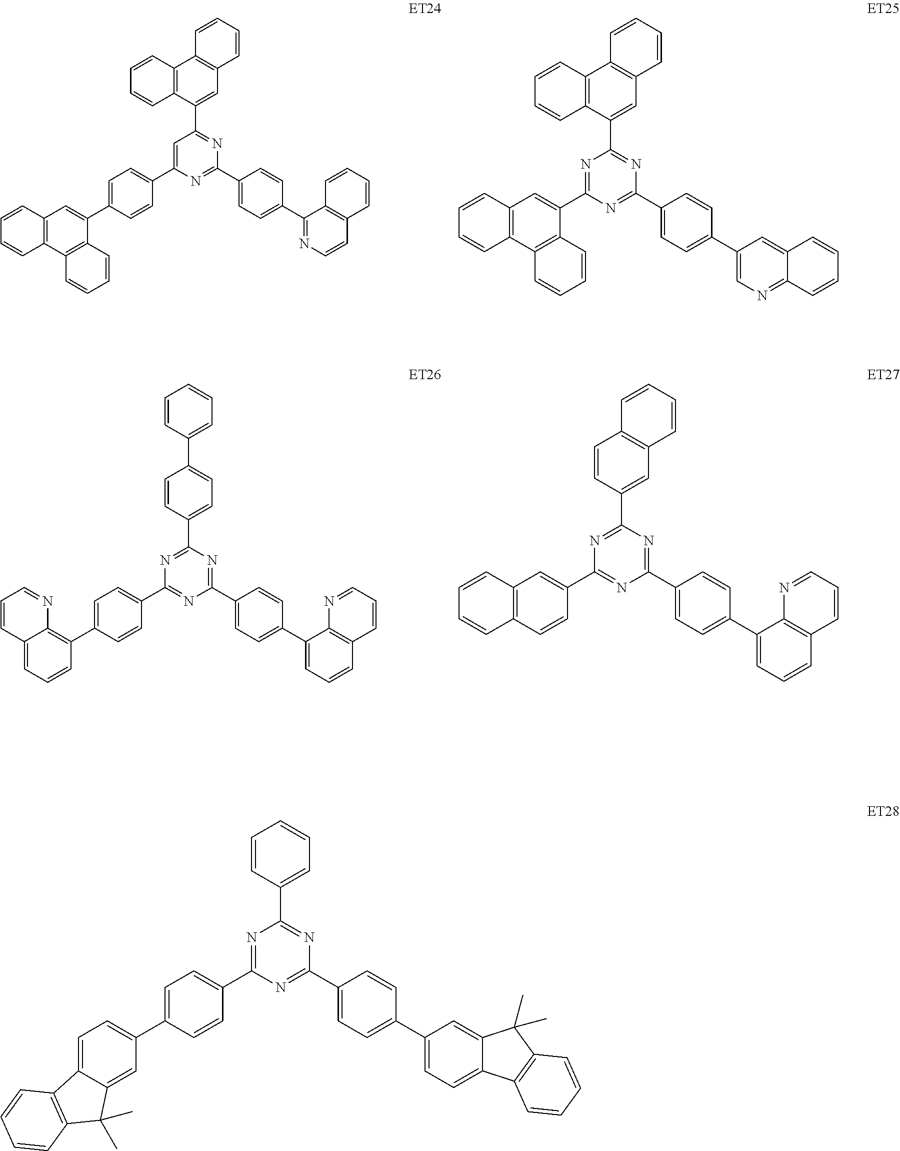 [SMILES: c1ccc2c(-c3ccc(-c4nc(-c5ccc(-c6cc7ccccc7c7ccccc67)cc5)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21]

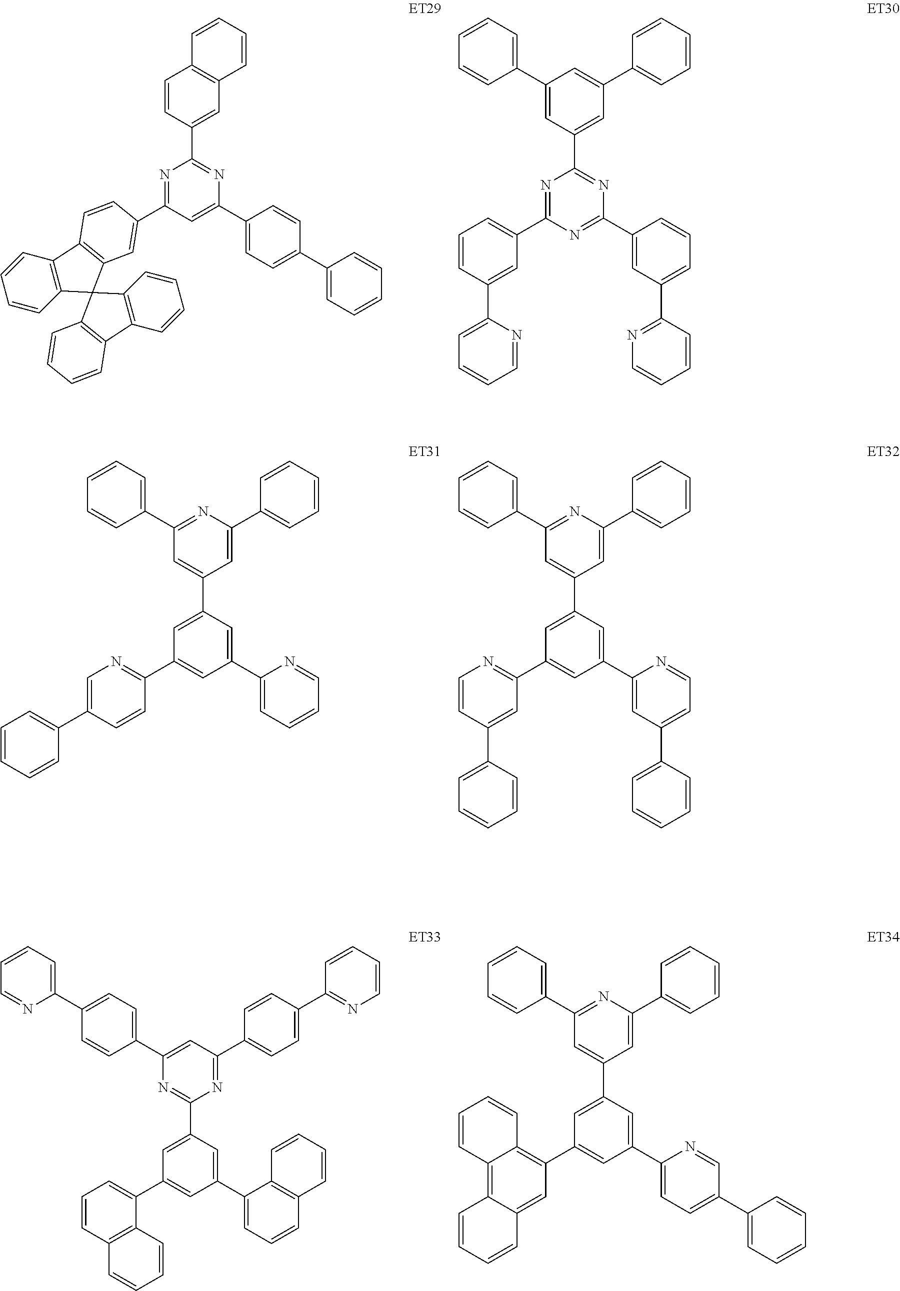

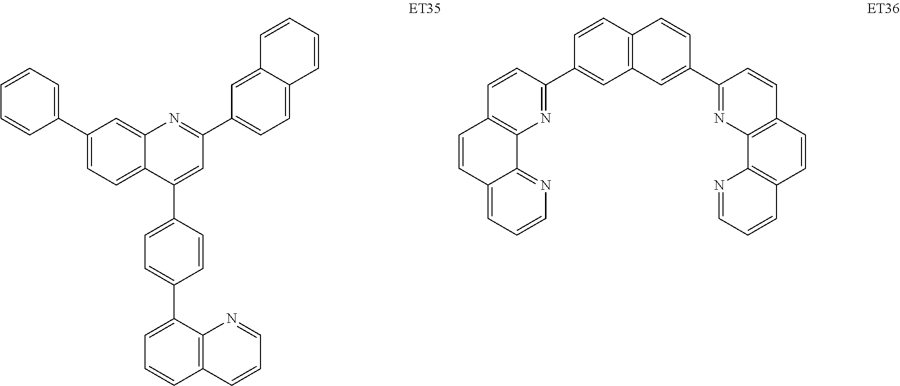 [SMILES: c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

In one or more embodiments, the electron transport region may include at least one of 2,9-dimethyl-4,7-diphenyl-1,10-phenanthroline (BCP), 4,7-dphenyl-1,10-phenanthroline (Bphen), Alq₃, BAlq, 3-(biphenyl-4-yl)-5-(4-tert-butylphenyl)-4-phenyl-4H-1,2,4-triazole (TAZ), or NTAZ:

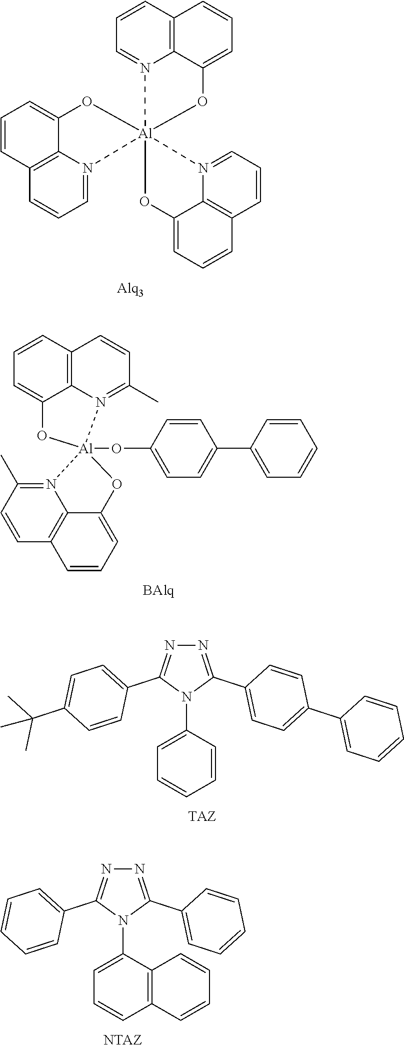

Thicknesses of the buffer layer, the hole blocking layer, and the electron control layer may each independently be in the range of about 20 Å to about 1,000 Å, for example, about 30 Å to about 300 Å. When the thicknesses of the buffer layer, the hole blocking layer, and the electron control layer are within these ranges, excellent hole blocking characteristics or excellent electron control characteristics may be obtained without a substantial increase in driving voltage.

A thickness of the electron transport layer may be in the range of about 100 Å to about 1,000 Å, for example, about 150 Å to about 500 Å. When the thickness of the electron transport layer is within the range described above, the electron transport layer may have satisfactory electron transport characteristics without a substantial increase in driving voltage.

The electron transport region 17 (for example, the electron transport layer in the electron transport region) may further include, in addition to the materials described above, a metal-containing material.

The metal-containing material may include at least one alkali metal complex or alkaline earth-metal complex. The alkali metal complex may include at least one metal ion that is a Li ion, a Na ion, a K ion, a Rb ion, or a Cs ion, and the alkaline earth-metal complex may include at least one metal ion that is a Be ion, a Mg ion, a Ca ion, a Sr ion, or a Ba ion. A ligand coordinated with the metal ion of the alkali metal complex or the alkaline earth-metal complex may be a hydroxy quinoline, a hydroxy isoquinoline, a hydroxy benzoquinoline, a hydroxy acridine, a hydroxy phenanthridine, a hydroxy phenyloxazole, a hydroxy phenylthiazole, a hydroxy diphenyloxadiazole, a hydroxy diphenylthiadiazole, a hydroxy phenylpyridine, a hydroxy phenylbenzimidazole, a hydroxy phenylbenzothiazole, a bipyridine, a phenanthroline, or a cyclopentadiene, but embodiments of the present disclosure are not limited thereto.

In one or more embodiments, the metal-containing material may include a Li complex. The Li complex may include, for example, Compound ET-D1 (Liq) or ET-D2:

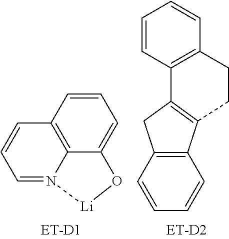

The electron transport region 17 may include an electron injection layer that facilitates the injection of electrons from the second electrode 19. The electron injection layer may directly contact the second electrode 19.

The electron injection layer may have i) a single-layered structure including a single layer including a single material, ii) a single-layered structure including a single layer including a plurality of different materials, or iii) a multi-layered structure having a plurality of layers including a plurality of different materials.

The electron injection layer may include an alkali metal, an alkaline earth metal, a rare earth metal, an alkali metal compound, an alkaline earth-metal compound, a rare earth metal compound, an alkali metal complex, an alkaline earth-metal complex, a rare earth metal complex, or any combinations thereof.

The alkali metal may be Li, Na, K, Rb, or Cs. In one or more embodiments, the alkali metal may be Li, Na, or Cs. In one or more embodiments, the alkali metal may be Li or Cs, but embodiments of the present disclosure are not limited thereto.

The alkaline earth metal may be Mg, Ca, Sr, or Ba.

The rare earth metal may be Sc, Y, Ce, Tb, Yb, or Gd.

The alkali metal compound, the alkaline earth-metal compound, and the rare earth metal compound may be oxides or halides (for example, fluorides, chlorides, bromides, or iodides) of the alkali metal, the alkaline earth-metal, or the rare earth metal.

The alkali metal compound may be an alkali metal oxide, such as Li₂O, Cs₂O, or K₂O, or an alkali metal halide, such as LiF, NaF, CsF, KF, LiI, NaI, CsI, or KI. In one or more embodiments, the alkali metal compound may be LiF, Li₂O, NaF, LiI, NaI, CsI, or KI, but embodiments of the present disclosure are not limited thereto.

The alkaline earth-metal compound may be an alkaline earth-metal oxide, such as BaO, SrO, CaO, BaₓSr₁₋ₓO (0<x<1), or BaₓCa₁₋ₓO (0<x<1). In one or more embodiments, the alkaline earth-metal compound may be BaO, SrO, or CaO, but embodiments of the present disclosure are not limited thereto.

The rare earth metal compound may be YbF₃, ScF₃, ScO₃, Y₂O₃, Ce₂O₃, GdF₃, or TbF₃. In one or more embodiments, the rare earth metal compound may be YbF₃, ScF₃, TbF₃, YbI₃, ScI₃, or TbI₃, but embodiments of the present disclosure are not limited thereto.

The alkali metal complex, the alkaline earth-metal complex, and the rare earth metal complex may include an ion of alkali metal, alkaline earth-metal, and rare earth metal as described above, and a ligand coordinated with a metal ion of the alkali metal complex, the alkaline earth-metal complex, or the rare earth metal complex may be hydroxy quinoline, hydroxy isoquinoline, hydroxy benzoquinoline, hydroxy acridine, hydroxy phenanthridine, hydroxy phenyloxazole, hydroxy phenylthiazole, hydroxy diphenyloxadiazole, hydroxy diphenylthiadiazole, hydroxy phenylpyridine, hydroxy phenylbenzimidazole, hydroxy phenylbenzothiazole, bipyridine, phenanthroline, or cyclopentadiene, but embodiments of the present disclosure are not limited thereto.

The electron injection layer may consist of an alkali metal, an alkaline earth metal, a rare earth metal, an alkali metal compound, an alkaline earth-metal compound, a rare earth metal compound, an alkali metal complex, an alkaline earth-metal complex, a rare earth metal complex, or any combinations thereof, as described above. In one or more embodiments, the electron injection layer may further include an organic material. When the electron injection layer further includes an organic material, an alkali metal, an alkaline earth metal, a rare earth metal, an alkali metal compound, an alkaline earth-metal compound, a rare earth metal compound, an alkali metal complex, an alkaline earth-metal complex, a rare earth metal complex, or any combination thereof may be homogeneously or non-homogeneously dispersed in a matrix including the organic material.

A thickness of the electron injection layer may be in a range of about 1 Å to about 100 Å, and, for example, about 3 Å to about 90 Å. When the thickness of the electron injection layer is within the range described above, the electron injection layer may have satisfactory electron injection characteristics without a substantial increase in driving voltage.

### Second Electrode 19

The second electrode 19 is located on the organic layer 10A having such a structure. The second electrode 19 may be a cathode which is an electron injection electrode, and in this regard, a material for forming the second electrode 19 may be a metal, an alloy, an electrically conductive compound, or a combination thereof, which have a relatively low work function.

The second electrode 19 may include at least one of lithium (Li), silver (Ag), magnesium (Mg), aluminum (Al), aluminum-lithium (Al—Li), calcium (Ca), magnesium-indium (Mg—In), magnesium-silver (Mg—Ag), ITO, or IZO, but embodiments of the present disclosure are not limited thereto. The second electrode 19 may be a transmissive electrode, a semi-transmissive electrode, or a reflective electrode.

The second electrode 19 may have a single-layered structure having a single layer or a multi-layered structure including two or more layers.

Another aspect provides a diagnostic composition including at least one polycyclic compound represented by Formula 1.

The polycyclic compound represented by Formula 1 provides high luminescence efficiency. Accordingly, a diagnostic composition including the polycyclic compound may have high diagnostic efficiency.

The diagnostic composition may be used in various applications including a diagnosis kit, a diagnosis reagent, a biosensor, and a biomarker.

### Explanation of Terms

The term “C₁-C₆₀ alkyl group” as used herein refers to a linear or branched saturated aliphatic hydrocarbon monovalent group having 1 to 60 carbon atoms, and non-limiting examples thereof include a methyl group, an ethyl group, a propyl group, an isobutyl group, a sec-butyl group, a tert-butyl group, a pentyl group, an isoamyl group, and a hexyl group. The term “C₁-C₆₀ alkylene group” as used herein refers to a divalent group having the same structure as the C₁-C₆₀ alkyl group.

The term “C₁-C₆₀ alkoxy group” used herein refers to a monovalent group represented by —OA₁₀₁ (wherein A₁₀₁ is the C₁-C₆₀ alkyl group), and examples thereof include a methoxy group, an ethoxy group, and an isopropyloxy group.

The term “C₂-C₆₀ alkenyl group” as used herein refers to a hydrocarbon group formed by substituting at least one carbon-carbon double bond in the middle or at the terminus of the C₂-C₆₀ alkyl group, and examples thereof include an ethenyl group, a propenyl group, and a butenyl group. The term “C₂-C₆₀ alkenylene group” as used herein refers to a divalent group having the same structure as the C₂-C₆₀ alkenyl group.

The term “C₂-C₆₀ alkynyl group” as used herein refers to a hydrocarbon group formed by substituting at least one carbon-carbon triple bond in the middle or at the terminus of the C₂-C₆₀ alkyl group, and examples thereof include an ethynyl group, and a propynyl group. The term “C₂-C₆₀ alkynylene group” as used herein refers to a divalent group having the same structure as the C₂-C₆₀ alkynyl group.

The term “C₃-C₁₀ cycloalkyl group” as used herein refers to a monovalent saturated hydrocarbon monocyclic group having 3 to 10 carbon atoms, and examples thereof include a cyclopropyl group, a cyclobutyl group, a cyclopentyl group, a cyclohexyl group, and a cycloheptyl group. The term “C₃-C₁₀ cycloalkylene group” as used herein refers to a divalent group having the same structure as the C₃-C₁₀ cycloalkyl group.

The term “C₁-C₁₀ heterocycloalkyl group” as used herein refers to a monovalent saturated monocyclic group having at least one heteroatom selected from N, O, P, Si, and S as a ring-forming atom instead of a carbon atom, and 1 to 10 carbon atoms, and non-limiting examples thereof include a tetrahydrofuranyl group, and a tetrahydrothiophenyl group. The term “C₁-C₁₀ heterocycloalkylene group” as used herein refers to a divalent group having the same structure as the C₁-C₁₀ heterocycloalkyl group.

The term “C₃-C₁₀ cycloalkenyl group” as used herein refers to a monovalent monocyclic group that has 3 to 10 carbon atoms and at least one carbon-carbon double bond in the ring thereof and no aromaticity, and non-limiting examples thereof include a cyclopentenyl group, a cyclohexenyl group, and a cycloheptenyl group. The term “C₃-C₁₀ cycloalkenylene group” as used herein refers to a divalent group having the same structure as the C₃-C₁₀ cycloalkenyl group.

The term “C₁-C₁₀ heterocycloalkenyl group” as used herein refers to a monovalent monocyclic group that has at least one heteroatom selected from N, O, P, Si, and S as a ring-forming atom instead of a carbon atom, 1 to 10 carbon atoms, and at least one carbon-carbon double bond in its ring and no aromaticity. Examples of the C₁-C₁₀ heterocycloalkenyl group are a 2,3-dihydrofuranyl group, and a 2,3-dihydrothiophenyl group. The term “C₁-C₁₀ heterocycloalkenylene group” as used herein refers to a divalent group having the same structure as the C₁-C₁₀ heterocycloalkenyl group.

The term “C₆-C₆₀ aryl group” as used herein refers to a monovalent group having a carbocyclic aromatic system having 6 to 60 carbon atoms, and the term “C₆-C₆₀ arylene group” as used herein refers to a divalent group having a carbocyclic aromatic system having 6 to 60 carbon atoms. Examples of the C₆-C₆₀ aryl group include a phenyl group, a naphthyl group, an anthracenyl group, a phenanthrenyl group, a pyrenyl group, and a chrysenyl group. When the C₆-C₆₀ aryl group and the C₆-C₆₀ arylene group each include two or more rings, the rings may be fused to each other.

The term “C₁-C₆₀ heteroaryl group” as used herein refers to a monovalent group having a cyclic aromatic system that has at least one heteroatom selected from N, O, P, Si, and S as a ring-forming atom instead of a carbon atom, and 1 to 60 carbon atoms. The term “C₁-C₆₀ heteroarylene group” as used herein refers to a divalent group having a cyclic aromatic system that has at least one heteroatom selected from N, O, P, and S as a ring-forming atom instead of a carbon atom, and 1 to 60 carbon atoms. Examples of the C₁-C₆₀ heteroaryl group include a pyridinyl group, a pyrimidinyl group, a pyrazinyl group, a pyridazinyl group, a triazinyl group, a quinolinyl group, and an isoquinolinyl group. When the C₆-C₆₀ heteroaryl group and the C₆-C₆₀ heteroarylene group each include two or more rings, the rings may be fused to each other.

The term “C₆-C₆₀ aryloxy group” used herein refers to —OA₁₀₂ (where A₁₀₂ is the C₆-C₆₀ aryl group), and the C₆-C₆₀ arylthio group is —SA₁₀₃ (where A₁₀₃ is the C₆-C₆₀ aryl group), and the C₆-C₆₀ arylalkyl group is —(CR₂)ₙA₁₀₄ (where A₁₀₄ is the C₆-C₅₉ aryl group, R is H or a C₁-C₁₀ alkyl group, and n is an integer from 1 to 10).

The term “substituted or unsubstituted C₁-C₆₀ heteroaryloxy group” as used herein refers to —OA₁₀₂ (where A₁₀₂ is the C₁-C₆₀ heteroaryl group). The term “substituted or unsubstituted C₁-C₆₀ heteroarylthio group” as used herein is —SA₁₀₃ (where A₁₀₃ is the C₁-C₆₀ heteroaryl group). The term “substituted or unsubstituted C₂-C₆₀ heteroarylalkyl group” as used herein is —(CR₂)ₙA₁₀₄ (where A₁₀₄ is the C₁-C₅₉ heteroaryl group, R is H or a C₁-C₁₀ alkyl group, and n is an integer from 1 to 10).

The term “monovalent non-aromatic condensed polycyclic group” as used herein refers to a monovalent group (for example, having 8 to 60 carbon atoms) having two or more rings condensed to each other, only carbon atoms as ring-forming atoms, and no aromaticity in its entire molecular structure. Examples of the monovalent non-aromatic condensed polycyclic group include a fluorenyl group. The term “divalent non-aromatic condensed polycyclic group” as used herein refers to a divalent group having the same structure as a monovalent non-aromatic condensed polycyclic group.

The term “monovalent non-aromatic condensed heteropolycyclic group” as used herein refers to a monovalent group (for example, having 2 to 60 carbon atoms) having two or more rings condensed to each other, a heteroatom selected from N, O, P, Si, and S, other than carbon atoms, as a ring-forming atom instead of a carbon atom, and no aromaticity in its entire molecular structure. Examples of the monovalent non-aromatic condensed heteropolycyclic group include a carbazolyl group. The term “divalent non-aromatic condensed heteropolycyclic group” as used herein refers to a divalent group having the same structure as a monovalent non-aromatic condensed heteropolycyclic group.

The term “C₅-C₃₀ carbocyclic group” as used herein refers to a saturated or unsaturated cyclic group having, as a ring-forming atom, 5 to 30 carbon atoms only. The C₅-C₃₀ carbocyclic group may be a monocyclic group or a polycyclic group.

The term “C₁-C₃₀ heterocyclic group” as used herein refers to a saturated or unsaturated cyclic group having, as a ring-forming atom, at least one heteroatom selected from N. O, Si, P, and S as ring members instead of a carbon atom, and 1 to 30 carbon atoms. The C₁-C₆₀ heterocyclic group may be a monocyclic group or a polycyclic group.

In one or more embodiments, the π electron-deficient nitrogen-containing C₁-C₆₀ cyclic group may be an imidazole group, a pyrazole group, a thiazole group, an isothiazole group, an oxazole group, an isoxazole group, a pyridine group, a pyrazine group, a pyridazine group, a pyrimidine group, an indazole group, a purine group, a quinoline group, an isoquinoline group, a benzoquinoline group, a benzoisoquinoline group, a phthalazine group, a naphthyridine group, a quinoxaline group, a benzoquinoxaline group, a quinazoline group, a cinnoline group, a phenanthridine group, an acridine group, a phenanthroline group, a phenazine group, a benzimidazole group, an isobenzothiazole group, a benzoxazole group, a benzoisoxazole group, a triazole group, a tetrazole group, an oxadiazole group, a triazine group, a thiadiazole group, an imidazopyridine group, an imidazopyrimidine group, an azacarbazole group, an azadibenzofuran group, an azadibenzothiophene group, an azadibenzosilole group, an acridine group, or a pyridopyrazine group.

For example, the π electron-deficient nitrogen-free cyclic group may be a π electron-rich C₃-C₆₀ cyclic group, and the π electron-rich C₃-C₆₀ cyclic group may be a benzene group, a heptalene group, an indene group, a naphthalene group, an azulene group, an indacene group, acenaphthylene group, a fluorene group, a spiro-bifluorene group, a benzofluorene group, a dibenzofluorene group, a phenalene group, a phenanthrene group, an anthracene group, a fluoranthene group, a triphenylene group, a pyrene group, a chrysene group, a naphthacene group, a picene group, a perylene group, a pentacene group, a hexacene group, a pentaphene group, a rubicene group, a coronene group, an ovalene group, a pyrrole group, a furan group, a thiophene group, an isoindole group, an indole group, an indene group, a benzofuran group, a benzothiophene group, a benzosilole group, a naphthopyrrole group, a naphthofuran group, a naphthothiophene group, a naphthosilole group, a benzocarbazole group, a dibenzocarbazole group, a dibenzofuran group, a dibenzothiophene group, a carbazole group, a dibenzosilole group, an indenocarbazole group, an indolocarbazole group, a benzofurocarbazole group, a benzothienocarbazole group, a benzosilolocarbazole group, a triindolobenzene group, a pyrrolophenanthrene group, a furanophenanthrene group, a thienophenanthrene group, a benzonaphthofuran group, a benzonaphthothiophene group, an (indolo)phenanthrene group, a (benzofuran)phenanthrene group, or a (benzothieno)phenanthrene group.

For example, the C₅-C₆₀ carbocyclic group may be a cyclopentane group, a cyclohexane group, a cyclohexene group, a benzene group, a naphthalene group, an anthracene group, a phenanthrene group, a triphenylene group, a pyrene group, a chrysene group, a 1,2,3,4-tetrahydronaphthalene group, cyclopentadiene group, an indene group, a fluorene group, a 5,6,7,8-tetrahydroisoquinoline group, a 5,6,7,8-tetrahydroquinoline group, an adamantane group, a norbonane group, or a norbonene group.

For example, the C₁-C₆₀ heterocyclic group may be a thiophene group, a furan group, a pyrrole group, a silole group, a borole group, phosphole group, a selenophene group, a germole group, a benzothiophene group, a benzofuran group, an indole group, a benzosilole group, a benzoborole group, a benzophosphole group, a benzoselenophene group, a benzogermole group, a dibenzothiophene group, a dibenzofuran group, a carbazole group, a dibenzosilole group, a dibenzoborole group, a dibenzophosphole group, a dibenzoselenophene group, a dibenzogermole group, a dibenzothiophene 5-oxide group, a 9H-fluorene-9-one group, a dibenzothiophene 5,5-dioxide group, an azabenzothiophene group, an azabenzofuran group, an azaindole group, an azaindene group, an azabenzosilole group, an azabenzoborole group, an azabenzophosphole group, an azabenzoselenophene group, an azabenzogermole group, an azadibenzothiophene group, an azadibenzofuran group, an azacarbazole group, an azafluorene group, an azadibenzosilole group, an azadibenzoborole group, an azadibenzophosphole group, an azadibenzoselenophene group, an azadibenzogermole group, an azadibenzothiophene 5-oxide group, an aza-9H-fluorene-9-one group, an azadibenzothiophene 5,5-dioxide group, a pyridine group, a pyrmidine group, a pyrazine group, a pyridazine group, a triazine group, a quinoline group, an isoquinoline group, a quinoxaline group, a quinazoline group, a phenanthroline group, a pyrazole group, an imidazole group, a triazole group, an oxazole group, an isooxazole group, a thiazole group, an isothiazole group, an oxadiazole group, a thiadiazole group, a benzopyrazole group, a benzimidazole group, a benzoxazole group, a benzothiazole group, a benzoxadiazole group, or a benzothiadiazole group.

The term “a π electron-deficient nitrogen-containing C₁-C₆₀ cyclic group, a π electron-rich C₃-C₆₀ cyclic group, a C₅-C₆₀ carbocyclic group, and a C₁-C₆₀ heterocyclic group” may be part of a condensed cycle or may be a monovalent, a divalent, a trivalent, a tetravalent, a pentavalent, or a hexavalent group, depending on the formula structure.

At least one substituent of the substituted π electron-deficient nitrogen-containing C₁-C₆₀ cyclic group, the substituted π electron-rich C₃-C₆₀ cyclic group, the substituted C₅-C₆₀ carbocyclic group, the substituted C₁-C₆₀ heterocyclic group, the substituted C₁-C₆₀ alkyl group, the substituted C₂-C₆₀ alkenyl group, the substituted C₂-C₆₀ alkynyl group, the substituted C₁-C₆₀ alkoxy group, the substituted C₃-C₁₀ cycloalkyl group, the substituted C₁-C₁₀ heterocycloalkyl group, the substituted C₃-C₁₀ cycloalkenyl group, the substituted C₁-C₁₀ heterocycloalkenyl group, the substituted C₆-C₆₀ aryl group, the substituted C₇-C₆₀ alkyl aryl group, the substituted C₆-C₆₀ aryloxy group, the substituted C₆-C₆₀ arylthio group, the substituted C₇-C₆₀ aryl alkyl group, the substituted C₁-C₆₀ heteroaryl group, the substituted C₁-C₆₀ heteroaryloxy group, the substituted C₁-C₆₀ heteroarylthio group, the substituted C₂-C₆₀ heteroarylalkyl group, the substituted monovalent non-aromatic condensed polycyclic group, and the substituted monovalent non-aromatic condensed heteropolycyclic group may be:

deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₆₀ alkyl group, a C₂-C₆₀ alkenyl group, a C₂-C₆₀ alkynyl group, or a C₁-C₆₀ alkoxy group;

a C₁-C₆₀ alkyl group, a C₂-C₆₀ alkenyl group, a C₂-C₆₀ alkynyl group, or a C₁-C₆₀ alkoxy group, each substituted with at least one of deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₆-C₆₀ aryloxy group, a C₆-C₆₀ arylthio group, a C₁-C₆₀ aryl alkyl group, a C₂-C₆₀ heteroaryl group, a C₁-C₆₀ heteroaryloxy group, a C₁-C₆₀ heteroarylthio group, a C₂-C₆₀ heteroarylalkyl group, a monovalent non-aromatic condensed polycyclic group, a monovalent non-aromatic condensed heteropolycyclic group, —N(Q₁₁)(Q₁₂), —Si(Q₁₃)(Q₁₄)(Q₁₅), —B(Q₁₆)(Q₁₇), or —P(═O)(Q₁₈)(Q₁₉);

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a C₁-C₆₀ heteroaryloxy group, a C₁-C₆₀ heteroarylthio group, C₂-C₆₀ heteroarylalkyl group, a monovalent non-aromatic condensed polycyclic group, or a monovalent non-aromatic condensed heteropolycyclic group;

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₆-C₆₀ aryloxy group, a C₆-C₆₀ arylthio group, a C₇-C₆₀ aryl alkyl group, a C₁-C₆₀ heteroaryl group, a C₁-C₆₀ heteroaryloxy group, a C₁-C₆₀ heteroarylthio group, a C₂-C₆₀ heteroarylalkyl group, a monovalent non-aromatic condensed polycyclic group, or a monovalent non-aromatic condensed heteropolycyclic group, each substituted with at least one of deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₆-C₆₀ aryloxy group, a C₆-C₆₀ arylthio group, a C₇-C₆₀ aryl alkyl group, a C₁-C₆₀ heteroaryl group, a C₁-C₆₀ heteroaryloxy group, a C₁-C₆₀ heteroarylthio group, a C₂-C₆₀ heteroarylalkyl group, a monovalent non-aromatic condensed polycyclic group, a monovalent non-aromatic condensed heteropolycyclic group, —N(Q₂₁)(Q₂₂), —Si(Q₂₃)(Q₂₄)(Q₂₅), —B(Q₂₆)(Q₂₇), or —P(═O)(Q₂₈)(Q₂₉); or

—N(Q₃₁)(Q₃₂), —Si(Q₃₃)(Q₃₄)(Q₃₅), —B(Q₃₆)(Q₃₇), and —P(═O)(Q₃₆)(Q₃₉),

wherein Q₁ to Q₉, Q₁₁ to Q₁₉, Q₂₁ to Q₂₉, and Q₃₁ to Q₃₉ may each independently be hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₆-C₆₀ aryloxy group, a C₆-C₆₀ arylthio group, a C₇-C₆₀ aryl alkyl group, a C₁-C₆₀ heteroaryl group, a C₁-C₆₀ heteroaryloxy group, a C₁-C₆₀ heteroarylthio group, a C₁-C₆₀ heteroarylalkyl group, a monovalent non-aromatic condensed polycyclic group, or a monovalent non-aromatic condensed heteropolycyclic group.

For example, Q₁ to Q₉, Q₁₁ to Q₁₉, Q₂₁ to Q₂₉ and Q₃₁ to Q₃₉ described herein may each independently be:

—CH₃, —CD₃, —CD₂H, —CDH₂, —CH₂CH₃, —CH₂CD₃, —CH₂CD₂H, —CH₂CDH₂, —CHDCH₃, —CHDCD₂H, —CHDCDH₂, —CHDCD₃, —CD₂CD₃, —CD₂CD₂H, or —CD₂CDH₂; or

an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, a phenyl group, a biphenyl group, or a naphthyl group, each unsubstituted or substituted with deuterium, a C₁-C₁₀ alkyl group, a phenyl group, or any combination thereof.

The term “room temperature” used herein refers to a temperature of about 25° C.

The terms “a biphenyl group, a terphenyl group, and a quaterphenyl group” used herein respectively refer to monovalent groups in which two, three, or four phenyl groups which are linked together via a single bond.

The terms “a cyano-containing phenyl group, a cyano-containing biphenyl group, a cyano-containing terphenyl group, and a cyano-containing quaterphenyl group” used herein respectively refer to a phenyl group, a biphenyl group, a terphenyl group, and a quaterphenyl group, each of which is substituted with at least one cyano group. In “a cyano-containing phenyl group, a cyano-containing biphenyl group, a cyano-containing terphenyl group, and a cyano-containing quaterphenyl group”, a cyano group may be substituted to any position of the corresponding group, and the “cyano-containing phenyl group, the cyano-containing biphenyl group, the cyano-containing terphenyl group, and the cyano-containing quaterphenyl group” may further include substituents other than a cyano group. For example, a phenyl group substituted with a cyano group, and a phenyl group substituted with a cyano group and a methyl group may all belong to “a cyano-containing phenyl group.”

Hereinafter, a compound and an organic light-emitting device according to embodiments are described in detail with reference to Synthesis Examples and Examples. However, the organic light-emitting device is not limited thereto. The wording “‘B’ was used instead of ‘A’” used in describing Synthesis Examples means that an amount of ‘A’ used was identical to an amount of ‘B’ used, in terms of a molar equivalent.

### EXAMPLES

### Synthesis Example 1: Synthesis of Compound 1 (diazoboranaphtoanthracene)

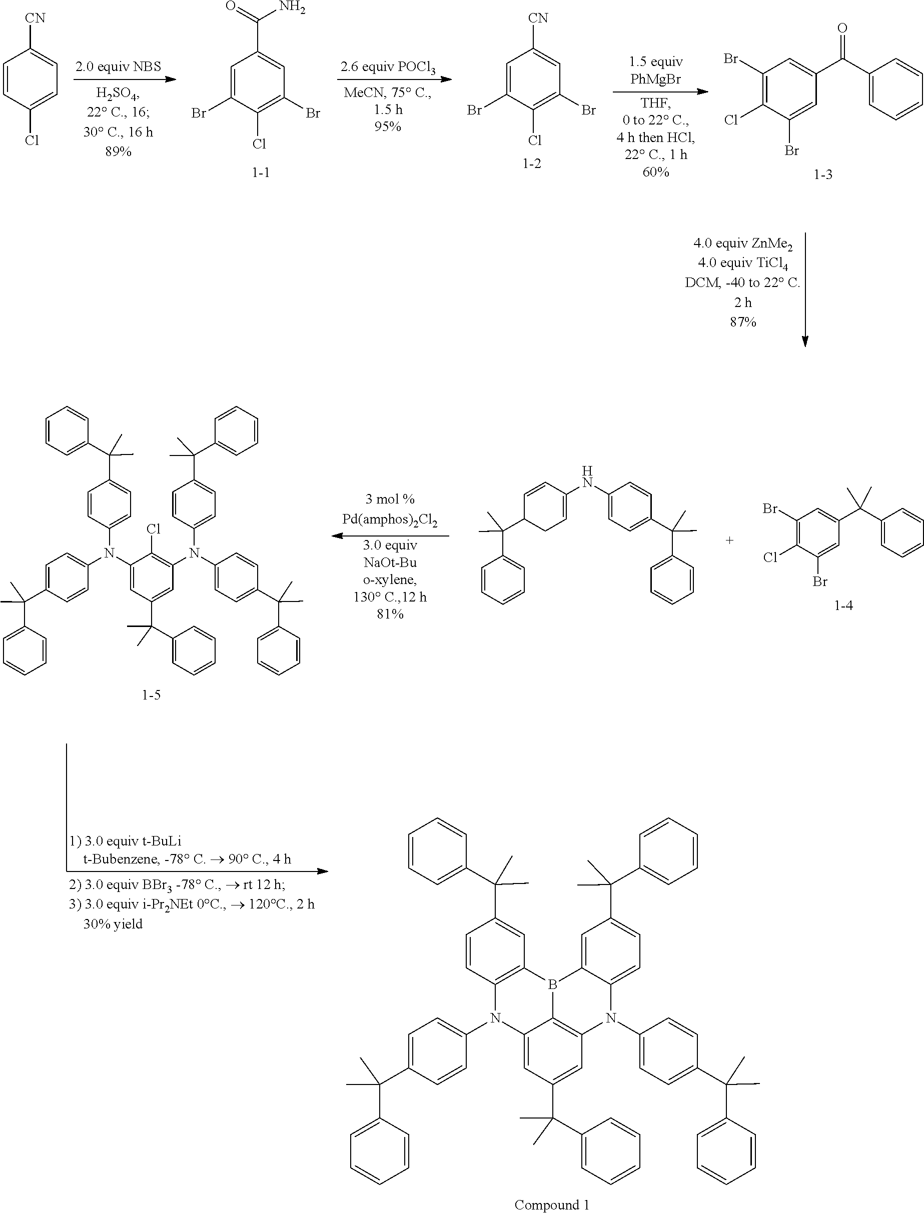

### Synthesis of Compound 1-1 (3,5-dibromo-4-chlorobenzamide)

4-chlorobenzonitrile (1.00 grams (g), 7.27 millimoles (mmol)) and a magnetic bar were placed in a 50 mL round-bottom flask, and the reaction vessel was cooled to 0° C. using an ice water bath, and then H₂SO₄ (10.8 mL) and N-bromosuccinimide (NBS) (2.59 g, 14.54 mmol) were added thereto and then stirred under nitrogen gas. The resultant mixture was stirred for 16 hours while the reaction temperature was slowly raised from 0° C. to room temperature and then, further stirred at 30° C. for 16 hours. The reaction solution was cooled to 0° C. using an ice water bath, and then, distilled water (10 mL) was added thereto and stirred at room temperature for 1 hour, and the reaction was terminated with aqueous ammonia at 0° C. The produced solid was filtered and dried with filter paper. The dry reaction product was separated by silica gel column chromatography (ethyl acetate (EtOAc):hexanes=1:2) to synthesize 3,5-dibromo-4-chlorobenzamide (2.03 g, 6.47 mmol, 89%) of Compound 1-1, which was a white solid.

Proton nuclear magnetic resonance (¹H NMR) spectroscopy (400 megahertz (MHz), de-dimethylsulfoxide (DMSO-d₆)): chemical shift (δ, ppm): 8.23 (s, 2H): ¹³C NMR (100 MHz, DMSO-d₆): δ (ppm) 164.2, 136.2, 135.1, 131.9, 122.9.

### Synthesis of Compound 1-2 (3,5-dibromo-4-chlorobenzonitrile)

3,5-dibromo-4-chlorobenzamide (Compound 1-1, 1.96 g, 6.25 mmol) was added to a 100 mL round-bottom flask, and acetonitrile (MeCN) (25.0 mL) was added thereto under nitrogen gas. POCl₃ (1.50 mL, 16.3 mmol) was added thereto and the reaction mixture was stirred at 75° C. for 1.5 hours. Thereafter, the reaction mixture was cooled to 0° C. using an ice bath, and saturated NaHCO₃ aqueous solution (30 mL) was added thereto to terminate the reaction. The resultant solid was filtered with filter paper, dried, and then separated by silica gel column chromatography (100% hexanes) to synthesize 3,5-dibromo-4-chlorobenzonitrile (1.76 g, 5.94 mmol, 95%) of Compound 1-2, which was a white solid.

¹H NMR (400 MHz, CDCl₃): δ (ppm) 7.89 (s, 2H), ¹³C NMR (100 MHz, CDCl₃): δ (ppm) 140.8, 135.4, 124.5, 115.4, 112.7.

### Synthesis of Compound 1-3 ((3,5-dibromo-4-chlorophenyl)(phenyl)methanone)

3,5-dibromo-4-chlorobenzonitrile (Compound 1-2, 500 mg, 1.70 mmol) was added to a 50 mL round-bottom flask, and tetrahydrofuran (THF) (5.1 mL) was added thereto under nitrogen gas. The reaction solution was cooled to 0° C. using an ice water bath, and then, C₆H₅MgBr(PhMgBr) (2.54 mL, 2.54 mmol) was slowly added thereto. The resultant mixture was stirred at room temperature for 4 hours, and then, 2N HCl (13.7 mL) was added at room temperature, followed by one hour of stirring. The reaction was terminated by adding saturated NaHCO₃ aqueous solution (5 mL), followed by extraction with CH₂Cl₂ (3×5 mL). MgSO₄ was added to a collected organic layer solution to remove water therefrom, followed by concentration by filtration. The concentrated reaction product was separated by silica gel column chromatography (EtOAc:hexanes=1:10), triturated with EtOAc, and filtered, thereby completing the preparation of Compound 1-3 (3,5-dibromo-4-chlorophenyl)(phenyl)methanone (380 mg, 1.02 mmol, 60%), which was a white solid compound.

¹H NMR (400 MHz, CDCl₃): δ (ppm) 8.01 (s, 2H), 7.78 (dd, J=8.0, 1.1 Hz, 2H), 7.68-7.64 (m, 1H), 7.54 (t, J=7.5 Hz, 1H); ¹³C NMR (100 MHz, CDCl₃): δ (ppm) 192.8, 139.1, 137.6, 136.1, 133.7, 133.3, 129.9, 128.7, 123.7.

### Synthesis: of Compound 1-4 (1,3-dibromo-2-chloro-5-(2-phenylpropan-2-yl)benzene)

A 25 mL round-bottom flask was cooled to −40° C. with dry ice and acetone, and then, TiCl₄ (2.96 mL, 3.96 mmol) and Zn(CH₃)₂ (2.47 mL, 3.96 mmol) were slowly added thereto under nitrogen gas and stirred for 30 minutes. (3,5-dibromo-4-chlorophenyl)(phenyl)methanone (Compound 1-3, 370 mg, 0.99 mmol) in CH₂Cl₂ (DCM) was slowly added to the reaction vessel, and then, was stirred for 2 hours while the temperature thereof was gradually raised to room temperature. The reaction solution was cooled to 0° C. using an ice water bath, and then, distilled water (10 mL) was added thereto to terminate the reaction, followed by extraction with CH₂Cl₂ (3×10 mL). MgSO₄ was added to a collected organic layer solution to remove water therefrom, followed by concentration by filtration. The concentrated reaction product was separated by silica gel column chromatography (100% hexanes), to obtain 1,3-dibromo-2-chloro-5-(2-phenylpropan-2-yl)benzene (334 mg, 0.86 mmol, 87%) of Compound 4, which was a white solid.

¹H NMR (400 MHz, CDCl₃): δ (ppm) 7.43 (s, 2H), 7.33-7.30 (m, 2H), 7.23-7.18 (m, 3H), 1.65 (s, 6H); ¹³C NMR (100 MHz, CDCl₃): δ (ppm) 152.1, 148.5, 132.0, 131.4, 128.4, 126.5, 126.3, 123.0, 42.8, 30.5

### Synthesis of Compound 1-5 (2-chloro-5-(2-phenylpropan-2-yl)-N¹,N¹,N³,N³-tetrakis(4-(2-phenylpropan-2-yl)phenyl)benzene-1,3-diamine)

In a glove box under a nitrogen atmosphere, bis(4-(2-phenylpropan-2-yl)phenyl)amine (12.3 g, 30.4 mmol), dichlorobis[di-tert-butyl(4-dimethylaminophenyl)phosphine]palladium(II) (Pd(amphos)₂Cl₂) (307 mg, 0.430 mmol), and sodium t-butoxide (NaOt-Bu) (3.48 g, 43.5 mmol) were placed in a 100 mL round-bottom flask, and sealed with rubber septa. Then, the round-bottom flask was taken out of the glove box. Nitrogen gas was flown into the round-bottom flask containing reactants for 5 minutes, and then, 1,3-dibromo-2-chloro-5-(2-phenylpropan-2-yl)benzene dissolved in o-xylene (5 mL) (Compound 1-4, 5.58 g, 14.5 mmol) and o-xylene (53 mL) were added thereto, and then, stirred at 130° C. for 12 hours. The reaction solution was cooled to room temperature, and extracted with CH₂Cl₂ (3×20 mL), and an organic layer solution was collected therefrom, and water was removed therefrom by using MgSO₄, and then filtered and concentrated. The concentrated reaction product was separated by silica gel column chromatography (EtOAc:hexanes=1:50) to obtain 2-chloro-5-(2-phenylpropan-2-yl)-N¹,N¹,N³,N₃-tetrakis(4-(2-phenylpropan-2-yl)phenyl)benzene-1,3-diamine of Compound 1-5 (12.2 g, 11.7 mmol, 81%), which was a white solid.

¹H NMR (400 MHz, CDCl₃): δ (ppm) 7.28-7.20 (m, 20H), 7.18-7.14 (m, 5H), 7.04-7.00 (m, 8H), 6.96 (s, 2H), 6.83-6.79 (m, 8H), 1.64 (s, 24H), 1.53 (s, 6H); ¹³C NMR (100 MHz, CDCl₃): δ (ppm) 150.9, 149.6, 145.2, 144.3, 140.8, 130.0, 128.0, 127.9, 127.9, 127.2, 127.1, 126.8, 128.5, 125.7, 125.5, 120.8, 42.8, 42.4, 30.8, 30.5.

### Synthesis of Compound 1 of diazoboranaphthoanthracene (2,7,12-tris(2-phenylpropan-2-yl)-5,9-bis(4-(2-phenylpropan-2-yl)phenyl)-5,9-dihydro-5,9-diaza-13b-boranaphtho[3,2,1-de]anthracene)

2-chloro-5-(2-phenylpropan-2-yl)-N¹,N¹,N³,N³-tetrakis(4-(2-phenylpropan-2-yl)phenyl)benzene-1,3-diamine (Compound 1-5, 100 mg, 0.0960 mmol) was added to a 50 mL round-bottom flask, and then, t-Bu-benzene (0.20 mL) was added thereto under nitrogen gas. The resultant mixture was cooled to −78° C. by using dry ice and acetone, and then, tert-butyl lithium (t-BuLi) (0.170 mL, 0.290 mmol) was slowly added and stirred at 90° C. for 4 hours. The temperature was lowered to −78° C., and BBr₃ (0.0280 mL, 0.290 mmol) was slowly added thereto, followed by twelve hours of stirring at room temperature. The temperature was lowered to 0° C. using an ice water bath, and then, diisopropylethylamine (i-Pr2NEt) (0.0500 mL, 0.290 mmol) was slowly added thereto and stirred at 120° C. for 2 hours. The reaction solution was cooled to 0′C using an ice water bath, and then, the reaction was terminated with 5% sodium acetate aqueous solution (5 mL), followed by extraction with EtOAc (3×5 mL). MgSO₄ was added to a collected organic layer solution to remove water therefrom, followed by concentration by filtration. The concentrated reaction product was separated by silica gel column chromatography (EtOAc:hexanes=1:100), and then, precipitated with diethylether (3×5 mL) and filtered to obtain Compound 1 of 2,7,12-tris(2-phenylpropan-2-yl)-5,9-bis(4-(2-phenylpropan-2-yl)phenyl)-5,9-dihydro-5,9-diaza-13b-boranaphtho[3,2,1-de]anthracene (30.0 mg, 0.300 mmol, 30%), which was a yellow solid.

¹H NMR (400 MHz, CDCl₃): δ (ppm) 8.89 (d, J=2.3 Hz, 2H), 7.42 (d, J=8.2 Hz, 4H), 7.35-7.20 (m, 17H), 7.18-7.06 (m, 12H), 7.00 (dd, J=7.8, 1.9 Hz, 2H), 6.72 (d, J=9.1 Hz, 2H), 5.92 (s, 2H), 1.79 (s, 12H), 1.77 (s, 12H), 1.38 (s, 6H); ¹³C NMR (100 MHz, CDCl₃): δ (ppm) 151.1, 150.8, 150.5, 150.4, 146.6, 145.9, 141.1, 139.7, 131.7, 130.4, 129.2, 128.1, 128.0, 127.6, 126.8, 126.8, 126.5, 125.8, 125.4, 125.2, 116.7, 104.1, 43.5, 43.0, 42.5, 31.0, 30.8, 30.0.

### Example 1

A glass substrate was cut to a size of 50 millimeters (mm)×50 mm×0.5 mm and then, sonicated in acetone isopropyl alcohol and pure water, each for 15 minutes, and then, washed by exposure to UV ozone for 30 minutes.

Subsequently, a first host (H1), a second host (H2), a sensitizer (S-2), and a fluorescent emitter (Compound 1) were co-deposited on the glass to form an emission layer having a thickness of 500 Å. At this time, a film was formed such that the first host and the second host were mixed at a weight ratio of 50:50, and the sensitizer and a fluorescent emitter were 10 wt % and 1.5 wt %, respectively, based on the total weight of the first host, the second host, the sensitizer, and the fluorescent emitter.

### Example 2

A glass substrate with an ITO electrode located thereon was cut to a size of 50 mm×50 mm×0.5 mm and then, sonicated in acetone isopropyl alcohol and pure water, each for 15 minutes, and then, washed by exposure to UV ozone for 30 minutes.

Then, HAT-CN was deposited on the ITO electrode (anode) on the glass substrate to form a hole injection layer having a thickness of 100 Å, NPB was deposited on the hole injection layer to form a first hole transport layer having a thickness of 500 Å, TCTA was deposited on the first hole transport layer to form a second hole transport layer having a thickness of 50 Å, and mCP was deposited on the second hole transport layer to form an electron blocking layer having a thickness of 50 Å.

A first host (H1), a second host (H2), a sensitizer (S-2), and a fluorescent emitter (Compound 1) were co-deposited on the electron blocking layer to form an emission layer having a thickness of 400 Å. At this time, the first host and the second host were mixed at a weight ratio of 60:40, and the amounts of the sensitizer and fluorescent emitter were adjusted to be 10 wt % and 0.5 wt %, respectively, based on the total weight of the first host, the second host, the sensitizer and the fluorescent emitter.

DBFPO was deposited on the emission layer to form a hole blocking layer having a thickness of 100 Å, and then DBFPO and Liq were co-deposited thereon at a weight ratio of 5:5 to form an electron transport layer having a thickness of 300 Å, and then, Liq was deposited on the electron transport layer to form an electron injection layer having a thickness of 10 Å, and Al was deposited on the electron injection layer to form a cathode having a thickness of 1000 Å, thereby completing the manufacture of an organic light-emitting device.

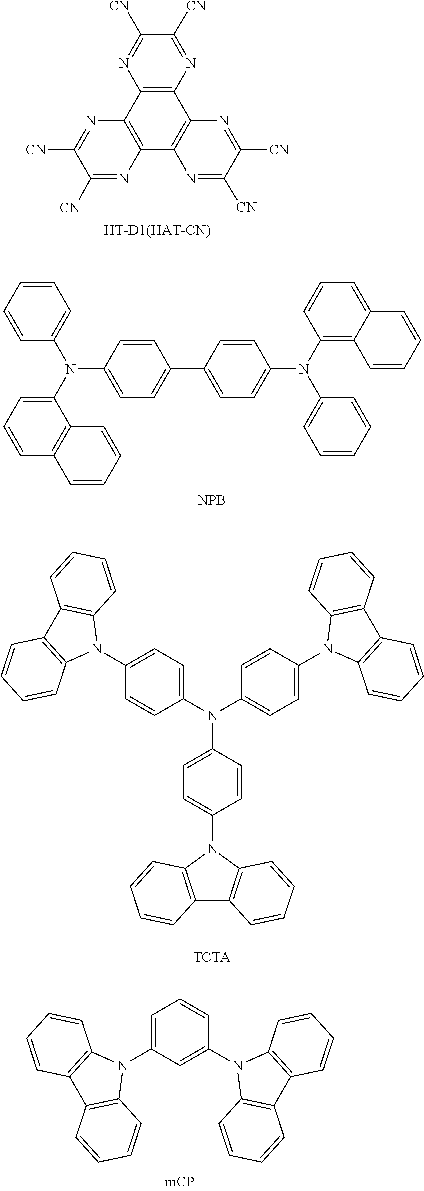

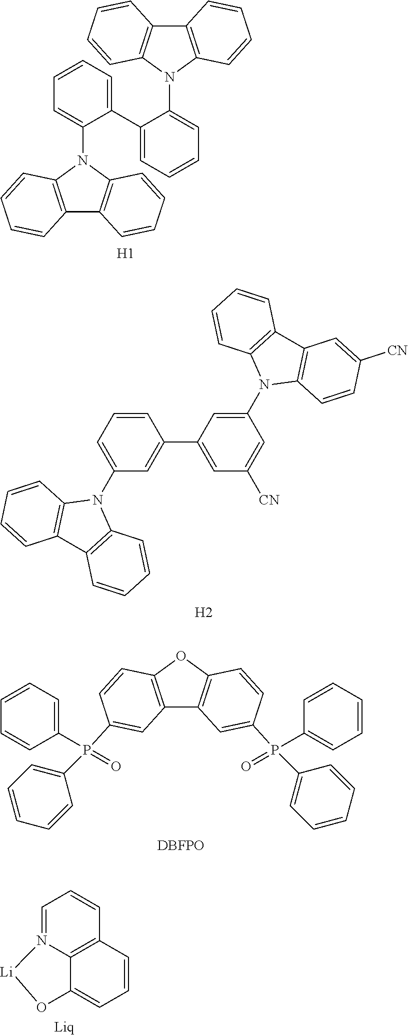

### Example 3

An organic light-emitting device was manufactured in the same manner as in Example 2, except that the sensitizer compound S-2 was not included when the emission layer was formed, and the fluorescent emitter compound shown in Table 8 was used at 1.5 wt %.

### Comparative Examples 1 and 2

Organic light-emitting devices were manufactured in the same manner as in Example 1, except that Compounds shown in Table 8 were each used instead of Compound 1 as a dopant when the emission layer was formed.

### Comparative Examples 3 and 4

Organic light-emitting devices were manufactured in the same manner as in Example 2, except that Compounds shown in Table 8 were each used instead of Compound 1 as a dopant when the emission layer was formed.

### Comparative Examples 5 and 6

Organic light-emitting devices were manufactured in the same manner as in Example 3, except that Compounds shown in Table 8 were each used instead of Compound 1 as a dopant when the emission layer was formed.

TABLE 8

| | Host | | | |
|---|---|---|---|---|
| | First | Second | | Fluorescent |
| Device No. | host | host | Sensitizer | emitter |
| Example 1 | H1 | H2 | S-2 | Compound 1 |
| Example 2 | H1 | H2 | S-2 | Compound 1 |
| Example 3 | H1 | H2 | — | Compound 1 |
| Comparative Example 1 | H1 | H2 | S-2 | Compound A |
| Comparative Example 2 | H1 | H2 | S-2 | Compound B |
| Comparative Example 3 | H1 | H2 | S-2 | Compound A |
| Comparative Example 4 | H1 | H2 | S-2 | Compound B |
| Comparative Example 5 | H1 | H2 | — | Compound A |
| Comparative Example 6 | H1 | H2 | — | Compound B |

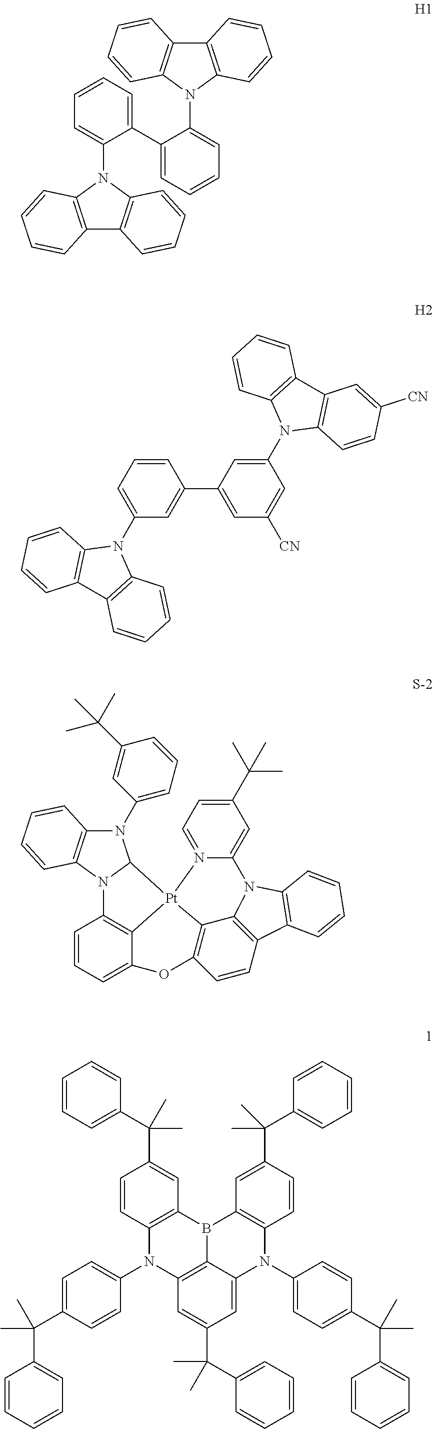

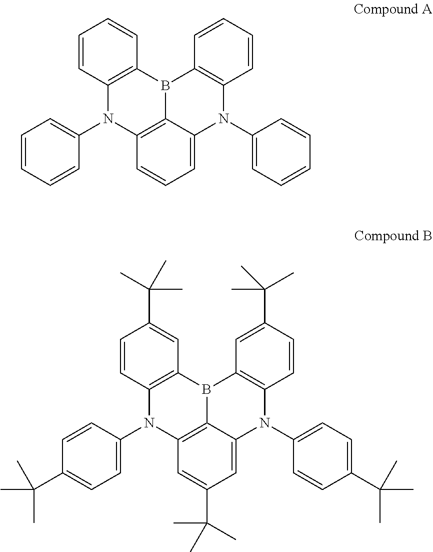 [SMILES: c1ccc(N2c3ccccc3B3c4ccccc4N(c4ccccc4)c4cccc2c43)cc1 ; CC(C)(C)c1ccc(N2c3ccc(C(C)(C)C)cc3B3c4cc(C(C)(C)C)ccc4N(c4ccc(C(C)(C)C)cc4)c4cc(C(C)(C)C)cc2c43)cc1]

### Evaluation Example 1: PL Spectrum Evaluation

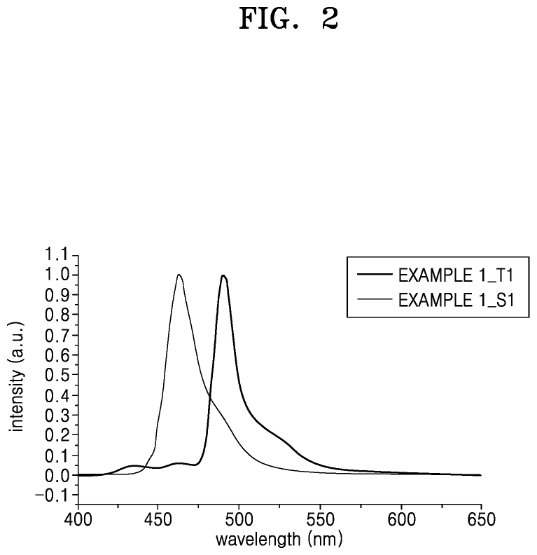

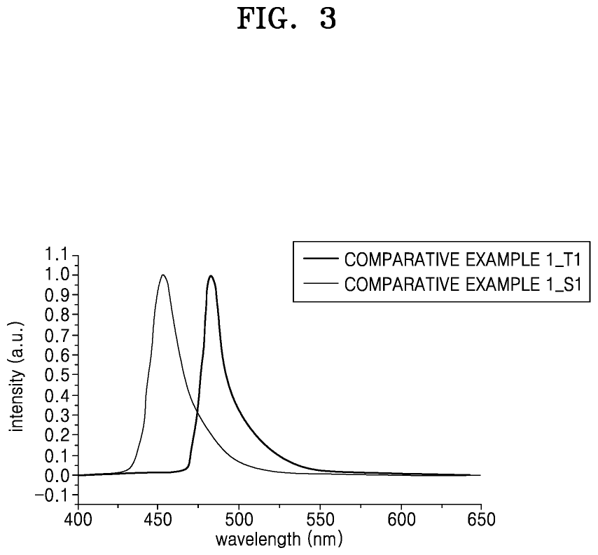

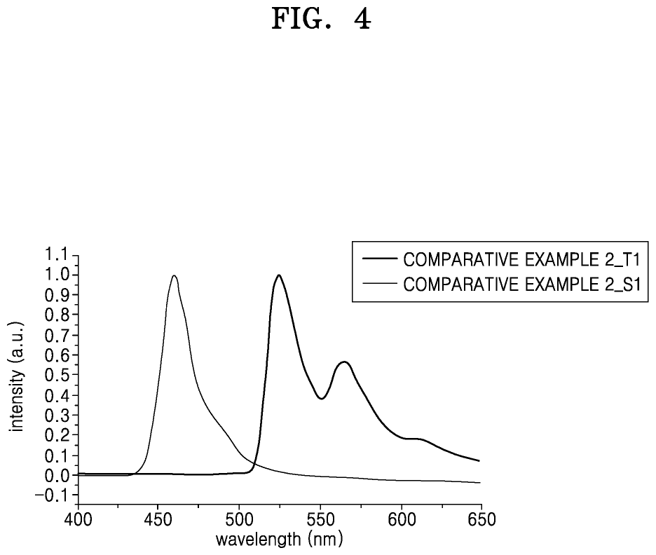

Compound 1 was diluted at a concentration of 10 mM in toluene, and then, the PL spectrum thereof was measured by using a ISC PC1 spectrofluorometer having a Xenon lamp mounted thereon at room temperature and 77K. This process cycle was repeatedly performed on Compounds A and B. Results thereof are shown in FIGS. 2 to 4.

### Evaluation Example 2: Decay Time Measurement

For each of the films produced in Example 1 and Comparative Examples 1 and 2, the PL spectrum was evaluated at room temperature by using the FluoTime 300 of PicoQuant Inc. and PLS340 (excitation wavelength=340 nm, spectrum width=20 nm), which was a pumping source of PicoQuant. In detail, the wavelength of the main peak of the spectrum obtained for each film was determined, and the number of photons emitted from the respective sample at the wavelength of the main peak by photon pulses (pulse width=500 picoseconds (ps)) applied by the PLS340 to the respective film was repeatedly measured based on time-correlated single photon counting (TCSPC), to obtain a TRPL curve which can be subjected to fitting. Two or more exponential decay functions, obtained therefrom, were subjected to fitting to calculate a decay time with respect to each film. In this regard, the same measurement was performed for the same measurement time as the measurement time to obtain the TRPL curve in the dark (a state where the light-low pulse signal incident to a certain film was blocked), thereby obtaining the background signal curve, which was then subjected to fitting for use as a baseline.

The function used for fitting is the same as Equation A below, and the largest value among the decay time (in microseconds, ps) obtained therefrom was taken.

$$f ( t ) = {{\sum }_{i = 1}}^{n} {A}_{i} exp ( - t / {T}_{decay , i} ) \qquad Equation A$$

TABLE 9

| | Dopant in | | | | Decay | Driving | |
|---|---|---|---|---|---|---|---|
| | emission | S₁ | T₁ | ΔE_{ST} | time | voltage | |
| | layer | (eV) | (eV) | (eV) | (μs) | (V) | EQE (%) |
| Exam- | Com- | 2.678 | 2.531 | 0.150 | 4.569 | 4.77 | 22.5 |
| ple 1 | pound 1 | | | | | | |
| Compar- | Com- | 2.737 | 2.567 | 0.170 | 7.231 | 4.93 | 19.2 |
| ative | pound A | | | | | | |
| Exam- | | | | | | | |
| ple 1 | | | | | | | |
| Compar- | Com- | 2.696 | 2.366 | 0.329 | 5.512 | 4.97 | 21.9 |

| | |
|---|---|
| ative | pound B |
| Exam- | |
| ple 2 | |

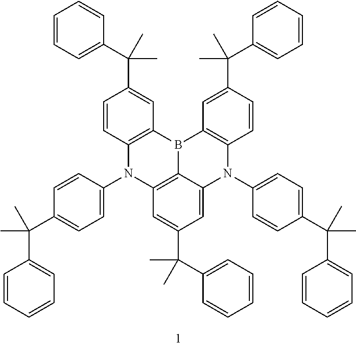 [SMILES: CC(C)(c1ccccc1)c1ccc(N2c3ccc(C(C)(C)c4ccccc4)cc3B3c4cc(C(C)(C)c5ccccc5)ccc4N(c4ccc(C(C)(C)c5ccccc5)cc4)c4cc(C(C)(C)c5ccccc5)cc2c43)cc1]

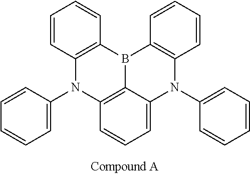 [SMILES: c1ccc(N2c3ccccc3B3c4ccccc4N(c4ccccc4)c4cccc2c43)cc1]

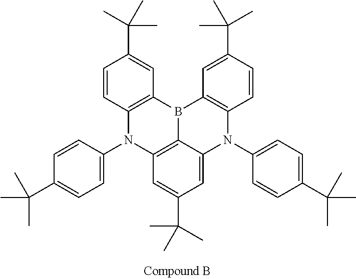 [SMILES: CC(C)(C)c1ccc(N2c3ccc(C(C)(C)C)cc3B3c4cc(C(C)(C)C)ccc4N(c4ccc(C(C)(C)C)cc4)c4cc(C(C)(C)C)cc2c43)cc1]

As shown in Table 9 and FIGS. 2 to 4, the band gap energy of Compound 1 used in Example 1 is smaller than those of Compounds A and B used in Comparative Examples 1 and 2, and the overlapping range of S₁ and T₁ energy level is wide, and thus, the reverse intersystem crossing occurs easily. Accordingly, it was confirmed that the organic light-emitting device of Example 1 has shorter decay time than Comparative Examples 1 and 2.

### Evaluation Example 3: Evaluation of Properties of Organic Light-Emitting Devices (1)

The driving voltage and quantum efficiency (%) were evaluated for each of the organic light-emitting devices manufactured in Example 2 and Comparative Examples 3 and 4, and results thereof are shown in Table 10.

TABLE 10

| | | Quantum | |
|---|---|---|---|
| | Dopant in emission | efficiency | Driving voltage |
| | layer | (%) | (%) |
| Example 2 | Compound 1 | 119 | 97 |
| Comparative | Compound A | 100 | 100 |
| Example 3 | | | |
| Comparative | Compound B | 110 | 101 |
| Example 4 | | | |

### Evaluation Example 4: Evaluation of Properties of Organic Light-Emitting Devices (2)

The driving voltage and quantum efficiency (%) were evaluated for each of the organic light-emitting devices manufactured in Example 3 and Comparative Examples 5 and 6, and results thereof are shown in Table 11.

TABLE 11

| | | Quantum | |
|---|---|---|---|
| | Dopant in emission | efficiency | Driving voltage |
| | layer | (%) | (%) |
| Example 3 | Compound 1 | 153 | 94 |
| Comparative | Compound A | 100 | 100 |
| Example 5 | | | |
| Comparative | Compound B | 151 | 98 |
| Example 6 | | | |

As shown in Tables 10 to 11, due to the use of the Compound 1 as a dopant, Example 2 and 3 have higher efficiency and lower driving voltage than Comparative Examples 3 to 6.

An organic light-emitting device, which includes a new structure of polycyclic compound in an emission layer, has high efficiency and long lifespan.

It should be understood that exemplary embodiments described herein should be considered in a descriptive sense and not for purposes of limitation. Descriptions of features or aspects within each exemplary embodiment should typically be considered as available for other similar features or aspects in other exemplary embodiments. While one or more exemplary embodiments have been described with reference to the figures, it will be understood by those of ordinary skill in the art that various changes in form and details may be made therein without departing from the spirit and scope as defined by the following claims.

1. A polycyclic compound represented by Formula 1: 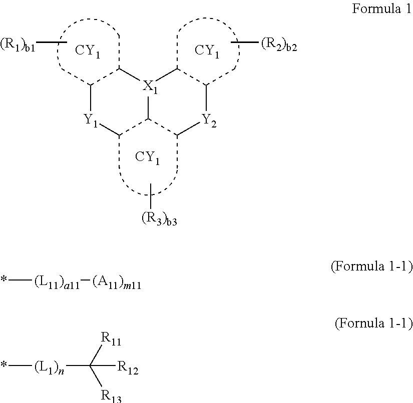
wherein, in Formulae 1, 1-1, and 1-2,
ring CY₁, ring CY₂, and ring CY₃ are each independently a C₅-C₃₀ carbocyclic group or a C₁-C₃₀ heterocyclic group,
X₁ is B, N, P, P(═O), P(═S), Al, Ga, As, C(R₄), Si(R₄), or Ge(R₄),
Y₁ and Y₂ are each independently O, S, Se, B(R₅), N(R₅), C(R₅)(R₆), Si(R₅)(R₆), Ge(R₅)(R₆), Ga(R₅), As(R₅), P(R₅), P(═O)(R₅), P(═S)(R₅), or Al(R₅),
R₁, R₂, R₃, R₄, R₅, and R₆ are each independently a group represented by Formula 1-1, hydrogen, deuterium, —F, —Cl, —Br, —I, —SF₅, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₇-C₆₀ alkyl aryl group, a substituted or unsubstituted C₆-C₆₀ aryloxy group, a substituted or unsubstituted C₆-C₆₀ arylthio group, a substituted or unsubstituted C₇-C₆₀ aryl alkyl group, a substituted or unsubstituted C₁-C₆₀ heteroaryl group, a substituted or unsubstituted C₁-C₆₀ heteroaryloxy group, a substituted or unsubstituted C₁-C₆₀ heteroarylthio group, a substituted or unsubstituted C₂-C₆₀ heteroarylalkyl group, a substituted or unsubstituted monovalent non-aromatic condensed polycyclic group, a substituted or unsubstituted monovalent non-aromatic condensed heteropolycyclic group, —N(Q₁)(Q₂), —Si(Q₃)(Q₄)(Q₅), —B(Q₆)(Q₇), or —P(═O)(Q₈)(Q₉),
at least one of R₁ to R₆ is a group represented by Formula 1-1,
two neighboring groups of R₁ to R₆ are optionally linked to each other to form a substituted or unsubstituted C₅-C₃₀ carbocyclic group or a substituted or unsubstituted C₁-C₃₀ heterocyclic group,
b1 to b3 are each independently an integer of 0 to 10,
when b1 is 2 or more, two or more of R₁(s) are identical to or different from each other, when b2 is 2 or more, two or more of R₂(s) are identical to or different from each other, and when b3 is 2 or more, two or more of R₃(s) are identical to or different from each other,
L₁₁ is a single bond, a substituted or unsubstituted C₅-C₃₀ carbocyclic group, or a substituted or unsubstituted C₁-C₃₀ heterocyclic group,
a11 is an integer from 1 to 3,
A₁₁ is a group represented by Formula 1-2,
m11 is an integer from 1 to 5,
L₁ is a substituted or unsubstituted C₁-C₂₀ alkylene group, a substituted or unsubstituted C₂-C₂₀ alkenylene group, a substituted or unsubstituted C₃-C₁₀ cycloalkylene group, a substituted or unsubstituted C₁-C₁₀ heterocycloalkylene group, a substituted or unsubstituted C₃-C₁₀ cycloalkenylene group, a substituted or unsubstituted C₁-C₁₀ heterocycloalkenylene group, a substituted or unsubstituted C₆-C₆₀ arylene group, a substituted or unsubstituted C₁-C₆₀ heteroarylene group, a substituted or unsubstituted divalent non-aromatic condensed polycyclic group, or a substituted or unsubstituted divalent non-aromatic condensed heteropolycyclic group,
n is an integer from 0 to 3, wherein, when n is 0, L₁ is not present, and when n is 2 or more, two or more of L₁(s) are identical to or different from each other,
R₁₁, R₁₂, and R₁₃ are each independently hydrogen, deuterium, —F, —Cl, —Br, —I, —SF₅, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₇-C₆₀ alkyl aryl group, a substituted or unsubstituted C₆-C₆₀ aryloxy group, a substituted or unsubstituted C₆-C₆₀ arylthio group, a substituted or unsubstituted C₇-C₆₀ aryl alkyl group, a substituted or unsubstituted C₁-C₆₀ heteroaryl group, a substituted or unsubstituted C₁-C₆₀ heteroaryloxy group, a substituted or unsubstituted C₁-C₆₀ heteroarylthio group, a substituted or unsubstituted C₂-C₆₀ heteroarylalkyl group, a substituted or unsubstituted monovalent non-aromatic condensed polycyclic group, a substituted or unsubstituted monovalent non-aromatic condensed heteropolycyclic group, —N(Q₁)(Q₂), —Si(Q₃)(Q₄)(Q₅), —B(Q₆)(Q₇), or —P(═O)(Q₅)(Q₉),
at least one of R₁₁, R₁₂, and R₁₃ is a substituted or unsubstituted C₆-C₆₀ aryl group,
* and *′ each indicate a binding site to a neighboring group, and
at least one substituent of the substituted C₅-C₃₀ carbocyclic group, the substituted C₁-C₃₀ heterocyclic group, the substituted C₁-C₆₀ alkyl group, the substituted C₂-C₆₀ alkenyl group, the substituted C₂-C₆₀ alkynyl group, the substituted C₁-C₆₀ alkoxy group, the substituted C₃-C₁₀ cycloalkyl group, the substituted C₁-C₁₀ heterocycloalkyl group, the substituted C₃-C₁₀ cycloalkenyl group, the substituted C₁-C₁₀ heterocycloalkenyl group, the substituted C₆-C₆₀ aryl group, the substituted C₇-C₆₀ alkyl aryl group, the substituted C₆-C₆₀ aryloxy group, the substituted C₆-C₆₀ arylthio group, the substituted C₇-C₆₀ aryl alkyl group, the substituted C₁-C₆₀ heteroaryl group, the substituted C₁-C₆₀ heteroaryloxy group, the substituted C₁-C₆₀ heteroarylthio group, the substituted C₂-C₆₀ heteroarylalkyl group, the substituted monovalent non-aromatic condensed polycyclic group, the substituted monovalent non-aromatic condensed heteropolycyclic group, the substituted C₁-C₂₀ alkylene group, the substituted C₂-C₂₀ alkenylene group, the substituted C₃-C₁₀ cycloalkylene group, the substituted C₁-C₁₀ heterocycloalkylene group, the substituted C₃-C₁₀ cycloalkenylene group, the substituted C₁-C₁₀ heterocycloalkenylene group, the substituted C₆-C₆₀ arylene group, the substituted C₁-C₆₀ heteroarylene group, the substituted divalent non-aromatic condensed polycyclic group, and the substituted divalent non-aromatic condensed heteropolycyclic group is:
deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₆₀ alkyl group, a C₂-C₆₀ alkenyl group, a C₂-C₆₀ alkynyl group, or a C₁-C₆₀ alkoxy group;
a C₁-C₆₀ alkyl group, a C₂-C₆₀ alkenyl group, a C₂-C₆₀ alkynyl group, or a C₁-C₆₀ alkoxy group, each substituted with at least one of deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₆-C₆₀ aryloxy group, a C₆-C₆₀ arylthio group, a C₇-C₆₀ aryl alkyl group, a C₁-C₆₀ heteroaryl group, a C₁-C₆₀ heteroaryloxy group, a C₁-C₆₀ heteroarylthio group, a C₂-C₆₀ heteroarylalkyl group, a monovalent non-aromatic condensed polycyclic group, a monovalent non-aromatic condensed heteropolycyclic group, —Si(Q₁₁)(Q₁₂)(Q₁₃), —N(Q₁₄)(Q₁₅), —B(Q₁₆)(Q₁₇), or —P(═O)(Q₁₈)(Q₁₉);
a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₆-C₆₀ aryloxy group, a C₆-C₆₀ arylthio group, a C₇-C₆₀ aryl alkyl group, a C₁-C₆₀ heteroaryl group, a C₁-C₆₀ heteroaryloxy group, a C₁-C₆₀ heteroarylthio group, a s C₂-C₆₀ heteroarylalkyl group, a monovalent non-aromatic condensed polycyclic group, or a monovalent non-aromatic condensed heteropolycyclic group;
a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₆-C₆₀ aryloxy group, a C₆-C₆₀ arylthio group, a C₇-C₆₀ aryl alkyl group, a C₁-C₆₀ heteroaryl group, a C₁-C₆₀ heteroaryloxy group, a C₁-C₆₀ heteroarylthio group, a C₂-C₆₀ heteroarylalkyl group, a monovalent non-aromatic condensed polycyclic group, or a monovalent non-aromatic condensed heteropolycyclic group, each substituted with at least one of deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₆-C₆₀ aryloxy group, a C₆-C₆₀ arylthio group, a C₇-C₆₀ aryl alkyl group, a C₁-C₆₀ heteroaryl group, a C₁-C₆₀ heteroaryloxy group, a C₁-C₆₀ heteroarylthio group, a C₂-C₆₀ heteroarylalkyl group, a monovalent non-aromatic condensed polycyclic group, a monovalent non-aromatic condensed heteropolycyclic group, —Si(Q₂₁)(Q₂₂)(Q₂₃), —N(Q₂₄)(Q₂₅) —B(Q₂₆)(Q₂₇), or —P(O)(Q₂₅)(Q₂₉); or
—Si(Q₃₁)(Q₃₂)(Q₃₃), —N(Q₃₄)(Q₃₅), —B(Q₃₆)(Q₃₇), or —P(═O)(Q₃₅)(Q₃₉),
wherein Q₁ to Q₉, Q₁₁ to Q₁₉, Q₂₁ to Q₂₉, and Q₃₁ to Q₃₉ are each independently hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₇-C₆₀ alkyl aryl group, a substituted or unsubstituted C₆-C₆₀ aryloxy group, a substituted or unsubstituted C₆-C₆₀ arylthio group, a substituted or unsubstituted C₇-C₆₀ aryl alkyl group, a substituted or unsubstituted C₁-C₆₀ heteroaryl group, a substituted or unsubstituted C₁-C₆₀ heteroaryloxy group, a substituted or unsubstituted C₁-C₆₀ heteroarylthio group, a substituted or unsubstituted C₂-C₆₀ heteroarylalkyl group, a substituted or unsubstituted monovalent non-aromatic condensed polycyclic group, or a substituted or unsubstituted monovalent non-aromatic condensed heteropolycyclic group.

2. The polycyclic compound of claim 1, wherein ring CY₁, ring CY₂, and ring CY₃ are each independently:
group A;
group B;
a condensed ring in which two or more of group A are condensed with each other;
a condensed ring in which two or more group B are condensed with each other; or
a condensed ring in which at least one group A is condensed with at least one group B,
wherein group A is a cyclic diene group, an indene group, an azulene group, a benzene group, a naphthalene group, an anthracene group, a phenanthrene group, a tetracene group, a tetraphene group, a pyrene group, a chrysene group, a triphenylene group, or a fluorene group, and
wherein group B is a furan group, a thiophene group, a pyrrole group, borole group, a silole group, a pyrrolidine group, an imidazole group, a triazole group, an oxazole group, an isoxazole group, a thiazole group, an isothiazole group, a pyridine group, a pyrimidine group, a pyridazine group, a triazine group, an indole group, an isoindole group, an indolizine group, a quinoline group, an isoquinoline group, a quinoxaline group, an isoquinoxaline group, a carbazole group, a dibenzofuran group, a dibenzothiophene group, a dibenzosilole group, or a dibenzoborole group.

3. The polycyclic compound of claim 1, wherein ring CY₁, ring CY₂, and ring CY₃ are each independently a benzene group, a naphthalene group, an anthracene group, or a fluorene group.

4. The polycyclic compound of claim 1, wherein Y₁ and Y₂ are the same.

5. The polycyclic compound of claim 1, wherein
X₁ is B, N, P, P(═O), P(═S), or Al, and
Y₁ and Y₂ are each independently O, S, Se, B(R₅), N(R₅), C(R₅)(R₆), or Si(R₅)(R₆).

6. The polycyclic compound of claim 1, wherein L₁₁ is:
a single bond;
a benzene group, an indene group, a naphthalene group, an azulene group, a heptalene group, acenaphthylene group, a fluorene group, a phenalene group, a phenanthrene group, an anthracene group, a fluoranthene group, a triphenylene group, a pyrene group, a chrysene group, a pyridine group, a pyrimidine group, a pyrazine group, a quinoline group, an isoquinoline group, a benzoquinoline group, a phthalazine group, a naphthyridine group, a quinoxaline group, a quinazoline group, a cinnoline group, a phenanthridine group, an acridine group, a phenanthroline group, a phenazine group, a benzimidazole group, an isobenzothiazole group, a benzoxazole group, a benzoisoxazole group, a triazole group, a tetrazole group, an oxadiazole group, a triazine group, a thiadiazole group, an imidazopyridine group, an imidazopyrimidine group, a carbazole group, an azacarbazole group, a dibenzofuran group, a dibenzothiophene group, or a dibenzosilole group; or
a benzene group, an indene group, a naphthalene group, an azulene group, a heptalene group, acenaphthylene group, a fluorene group, a phenalene group, a phenanthrene group, an anthracene group, a fluoranthene group, a triphenylene group, a pyrene group, a chrysene group, a pyridine group, a pyrimidine group, a pyrazine group, a quinoline group, an isoquinoline group, a benzoquinoline group, a phthalazine group, a naphthyridine group, a quinoxaline group, a quinazoline group, a cinnoline group, a phenanthridine group, an acridine group, a phenanthroline group, a phenazine group, a benzimidazole group, an isobenzothiazole group, a benzoxazole group, a benzoisoxazole group, a triazole group, a tetrazole group, an oxadiazole group, a triazine group, a thiadiazole group, an imidazopyridine group, an imidazopyrimidine group, a carbazole group, an azacarbazole group, a dibenzofuran group, a dibenzothiophene group, or a dibenzosilole group, each substituted with at least one of deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ cycloalkenyl group, a C₁-C₁₀ heterocycloalkyl group, a C₁-C₁₀ heterocycloalkenyl group, a C₆-C₆₀ aryl group, a C₇-C₆₀ alkyl aryl group, a C₆-C₆₀ aryloxy group, a C₆-C₆₀ arylthio group, a C₇-C₆₀ aryl alkyl group, a C₁-C₆₀ heteroaryl group, a C₁-C₆₀ heteroaryloxy group, a C₁-C₆₀ heteroarylthio group, a C₂-C₆₀ heteroarylalkyl group, a monovalent non-aromatic condensed polycyclic group, or a monovalent non-aromatic condensed heteropolycyclic group.

7. The polycyclic compound of claim 1, wherein L₁₁ is
a single bond; or
a group represented by one of Formulae 3-1 to 3-46: 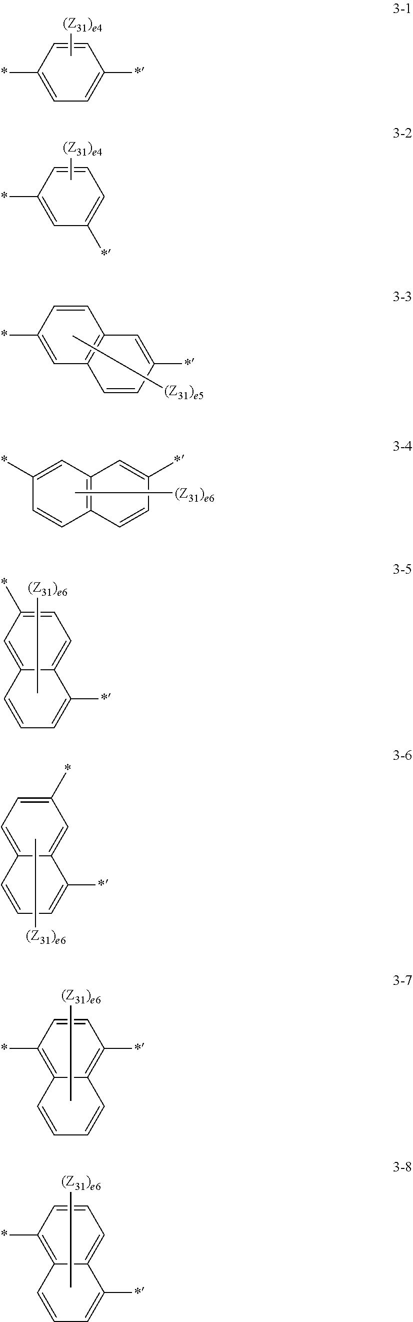 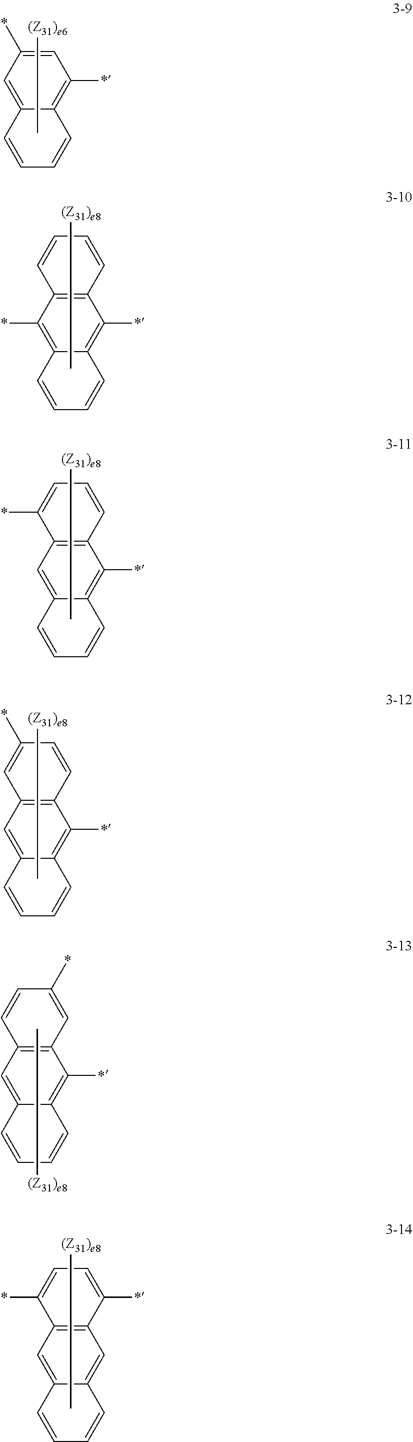 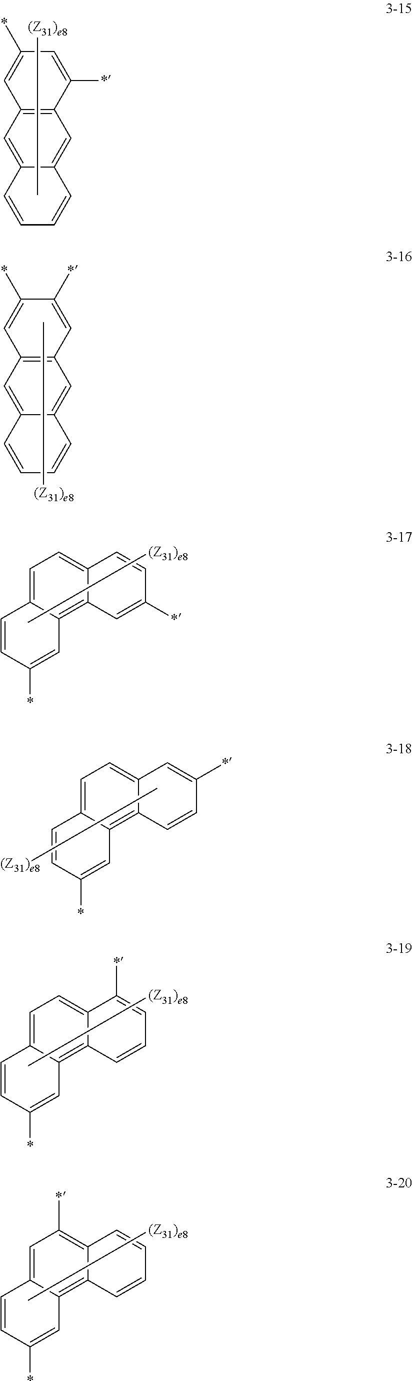 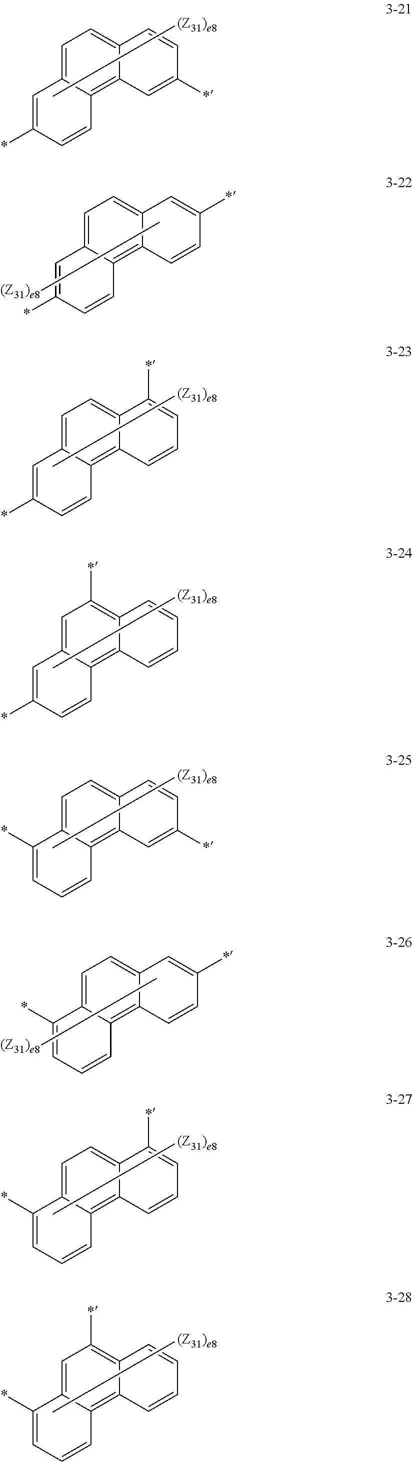 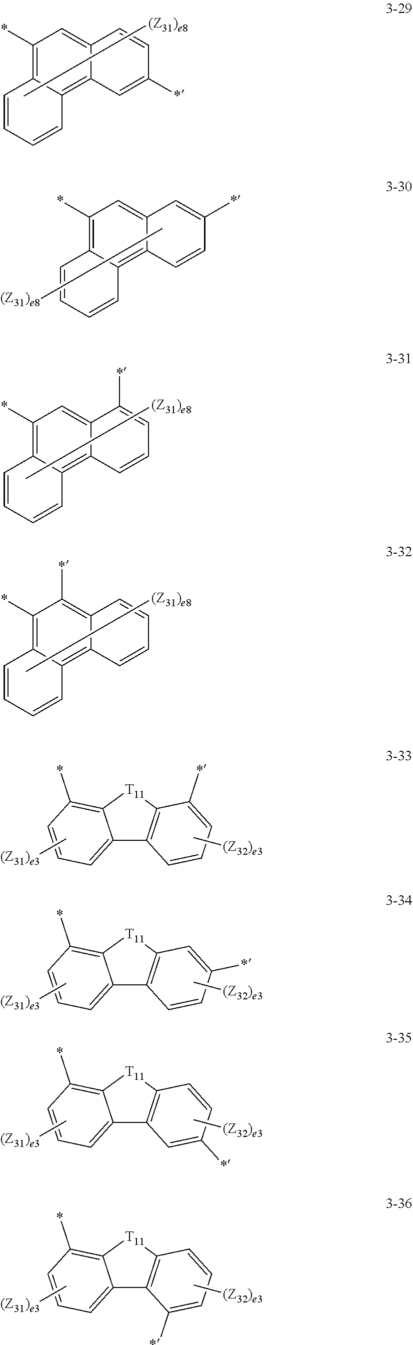 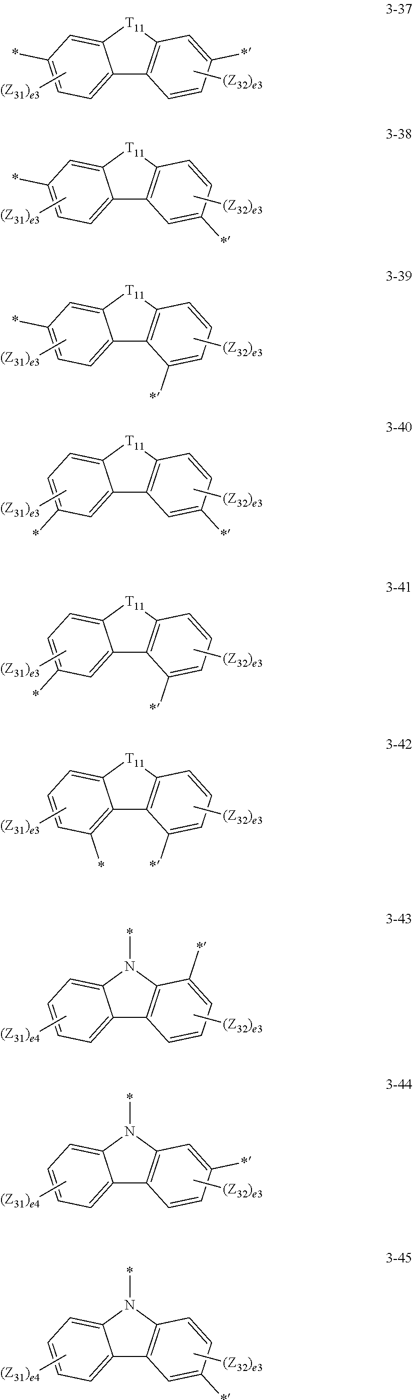 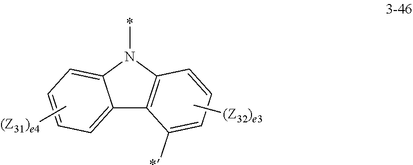
wherein, in Formulae 3-1 to 3-46,
T₁ is O, S, Si(Z₃₃)(Z₃₄), C(Z₃₃)(Z₃₄), or Se,
Z₃₁ to Z₃₄ are each independently hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ cycloalkenyl group, a C₁-C₁₀ heterocycloalkyl group, a C₁-C₁₀ heterocycloalkenyl group, a C₆-C₆₀ aryl group, a C₇-C₆₀ alkyl aryl group, a C₆-C₆₀ aryloxy group, a C₆-C₆₀ arylthio group, a C₇-C₆₀ aryl alkyl group, or a C₁-C₆₀ heteroaryl group,
e3 is an integer from 1 to 3,
e4 is an integer from 1 to 4,
e6 is an integer from 1 to 6,
e8 is an integer from 1 to 8, and
* and *′ each indicate a binding site to a neighboring atom.

8. The polycyclic compound of claim 1, wherein R₁, R₂, R₃, R₄, R₅, and R₆ are each independently:
a group represented by Formula 1-1;
hydrogen, deuterium, —F, —Cl, —Br, —I, a hydroxyl group, a cyano group (CN), a nitro group, an amino group, a C₁-C₆₀ alkyl group, or a C₁-C₆₀ alkoxy group;
a C₁-C₆₀ alkyl group or a C₁-C₆₀ alkoxy group, each substituted with at least one of deuterium, —F, —Cl, —Br, —I, a hydroxyl group, a cyano group, a nitro group, an amino group, a phenyl group, a biphenyl group, a naphthyl group, a fluorenyl group, a phenanthrenyl group, an anthracenyl group, a fluoranthenyl group, a triphenylenyl group, a pyrenyl group, or a chrysenyl group;
a cyclopentyl group, a cyclohexyl group, a cycloheptyl group, a cyclopentenyl group, a cyclohexenyl group, a cycloheptenyl group, a phenyl group, a biphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a phenanthrolinyl group, a benzimidazolyl group, a benzofuranyl group, a benzothiophenyl group, a benzoisothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, or a carbazolyl group; or
a cyclopentyl group, a cyclohexyl group, a cycloheptyl group, a cyclopentenyl group, a cyclohexenyl group, a cycloheptenyl group, a phenyl group, a biphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a phenanthrolinyl group, a benzimidazolyl group, a benzofuranyl group, a benzothiophenyl group, a benzoisothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, or a carbazolyl group, each substituted with at least one of deuterium, —F, —Cl, —Br, —I, a hydroxyl group, a cyano group, a nitro group, an amino group, a C₁-C₆₀ alkyl group, a C₇-C₆₀ aryl alkyl group, C₇-C₆₀ alkyl aryl group, a C₁-C₆₀ alkoxy group, a cyclopentyl group, a cyclohexyl group, a cycloheptyl group, a cyclopentenyl group, a cyclohexenyl group, a cycloheptenyl group, a phenyl group, a biphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a phenanthrolinyl group, a benzimidazolyl group, a benzofuranyl group, a benzothiophenyl group, a benzoisothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, or a carbazolyl group.

9. The polycyclic compound of claim 1, wherein at least two of R₁ to R₆ are each independently a group represented by Formula 1-1.

10. The polycyclic compound of claim 1, wherein R₁₁ to R₁₃ are each independently:
hydrogen, deuterium, —F, —Cl, —Br, —I, a hydroxyl group, a cyano group (CN), a nitro group, an amino group, a C₁-C₆₀ alkyl group, or a C₁-C₆₀ alkoxy group;
a C₁-C₆₀ alkyl group or a C₁-C₆₀ alkoxy group, each substituted with at least one of deuterium, —F, —Cl, —Br, —I, a hydroxyl group, a cyano group, a nitro group, an amino group, a phenyl group, a biphenyl group, a naphthyl group, a fluorenyl group, a phenanthrenyl group, an anthracenyl group, a fluoranthenyl group, a triphenylenyl group, a pyrenyl group, or a chrysenyl group;
a cyclopentyl group, a cyclohexyl group, a cycloheptyl group, a cyclopentenyl group, a cyclohexenyl group, a cycloheptenyl group, a phenyl group, a biphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a phenanthrolinyl group, a benzimidazolyl group, a benzofuranyl group, a benzothiophenyl group, a benzoisothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, or a carbazolyl group; or
a cyclopentyl group, a cyclohexyl group, a cycloheptyl group, a cyclopentenyl group, a cyclohexenyl group, a cycloheptenyl group, a phenyl group, a biphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a phenanthrolinyl group, a benzimidazolyl group, a benzofuranyl group, a benzothiophenyl group, a benzoisothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, or a carbazolyl group, each substituted with at least one of deuterium, —F, —Cl, —Br, —I, a hydroxyl group, a cyano group, a nitro group, an amino group, a C₁-C₆₀ alkyl group, a C₁-C₆₀ alkoxy group, a cyclopentyl group, a cyclohexyl group, a cycloheptyl group, a cyclopentenyl group, a cyclohexenyl group, a cycloheptenyl group, a phenyl group, a biphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a phenanthrolinyl group, a benzimidazolyl group, a benzofuranyl group, a benzothiophenyl group, a benzoisothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, or a carbazolyl group.

11. The polycyclic compound of claim 1, wherein m11 is 1 or 2.

12. The polycyclic compound of claim 1, wherein Formula 1-2 is represented by one of Formulae 1-2a to 1-2c: 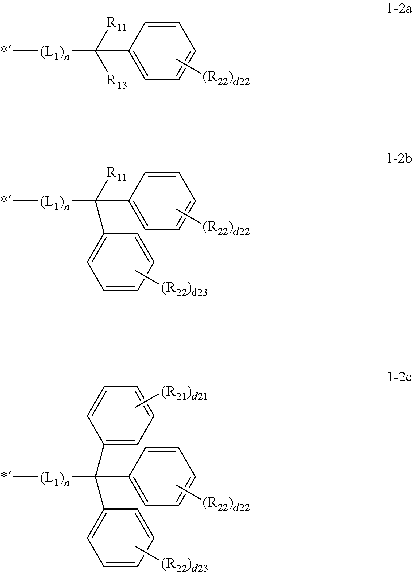
wherein, in Formulae 1-2a to 1-2c,
R₁₁, R₁₃, L₁, and n are each the same as described in claim 1,
R₂₁ to R₂₃ are each independently:
hydrogen, deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₆-C₆₀ aryloxy group, a C₆-C₆₀ arylthio group, a C₇-C₆₀ aryl alkyl group, a C₁-C₆₀ heteroaryl group, a C₁-C₆₀ heteroaryloxy group, a C₁-C₆₀ heteroarylthio group, a C₂-C₆₀ heteroarylalkyl group, a monovalent non-aromatic condensed polycyclic group, a monovalent non-aromatic condensed heteropolycyclic group, —Si(Q₂₁)(Q₂₂)(Q₂₃), —N(Q₂₄)(Q₂₅) —B(Q₂₆)(Q₂₇), or —P(═O)(Q₂₅)(Q₂₉), and
d21 to d23 are each independently an integer from 1 to 5, wherein when d21 is an integer of 2 or more, two or more of R₂₁(S) are identical to or different from each other, when d22 is an integer of 2 or more, two or more of R₂₂(s) are identical to or different from each other, and when d23 is an integer of 2 or more, two or more of R₂₃(s) are identical to or different from each other.

13. The polycyclic compound of claim 12, wherein, in Formulae 1-2a and 1-2b, R₁₁ and R₁₃ are each independently:
deuterium, —F, —Cl, —Br, —I, a hydroxyl group, a cyano group, a nitro group, an amino group, a C₁-C₆₀ alkyl group, or a C₁-C₆₀ alkoxy group; or
a C₁-C₆₀ alkyl group or a C₁-C₆₀ alkoxy group, each substituted with at least one of deuterium, —F, —Cl, —Br, —I, a hydroxyl group, a cyano group, a nitro group, an amino group, a phenyl group, a biphenyl group, a naphthyl group, a fluorenyl group, a phenanthrenyl group, an anthracenyl group, a fluoranthenyl group, a triphenylenyl group, a pyrenyl group, or a chrysenyl group,

14. The polycyclic compound of claim 1, wherein Formula 1 is represented by Formula 2: 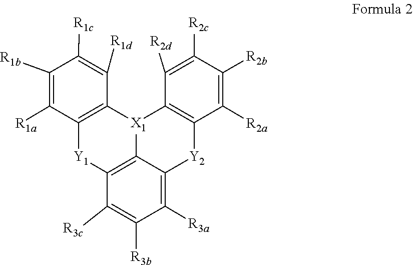
wherein, in Formula 2,
X₁, Y₁, and Y₂ are the same as described in claim 1,
R₁ₐ to R_{1d} are each the same as described in connection with R₁ in claim 1, R₂ₐ to R_{2d} are each the same as described in connection with R₂ in claim 1, and R₃ₐ to R_{3c} are each the same as described in connection with R₃ in claim 1, and
wherein:
(i) one of R₁ₐ to R_{1d} is a group represented by Formula 1-1; one of R₂ₐ to R_{2d} is a group represented by Formula 1-1; or one of R₃ₐ to R_{3c} is a group represented by Formula 1-1,
(ii) two of R₁ₐ to R_{1d} are each a group represented by Formula 1-1, two of R₂ₐ to R_{2d} are each a group represented by Formula 1-1, or two of R₃ₐ to R_{3c} are each a group represented by Formula 1-1,
(iii) three of R₁ₐ to R_{1d} are each a group represented by Formula 1-1; three of R₂ₐ to R_{2d} are each a group represented by Formula 1-1; or R₃ₐ to R_{3c} are each a group represented by Formula 1-1,
(iv) each of R₁ₐ to R_{1d} is a group represented by Formula 1-1; or each of R₂ₐ to R_{2d} is a group represented by Formula 1-1,
(v) one of R₁ₐ to R_{1d} is a group represented by Formula 1-1 and one of R₂ₐ to R_{2d} is a group represented by Formula 1-1; one of R₁ₐ to R_{1d} is a group represented by Formula 1-1 and one of R₃ₐ to R_{3c} is a group represented by Formula 1-1; or one of R₂ₐ to R_{2d} is a group represented by Formula 1-1 and one of R₃ₐ to R_{3c} is a group represented by Formula 1-1;
(vi) two of R₁ₐ to R_{1d} are each a group represented by Formula 1-1 and one of R₂ₐ to R_{2d} is a group represented by Formula 1-1; two of R₁ₐ to R_{1d} are each a group represented by Formula 1-1 and one of R₃ₐ to R_{3c} is a group represented by Formula 1-1; two of R₂ₐ to R_{2d} are each a group represented by Formula 1-1 and one of R₁ₐ to R_{1d} is a group represented by Formula 1-1; two of R₂ₐ to R_{2d} are each a group represented by Formula 1-1 and one of R₃ₐ to R_{3c} is a group represented by Formula 1-1; two of R₃ₐ to R_{3c} are each a group represented by Formula 1-1 and one of R₁ₐ to R_{1d} is a group represented by Formula 1-1; two of R₃ₐ to R_{3c} are each a group represented by Formula 1-1 and one of R₂ₐ to R_{2d} is a group represented by Formula 1-1; or one of R₁ₐ to R_{1d} is a group represented by Formula 1-1, one of R₂ₐ to R_{2d} is a group represented by Formula 1-1, and one of R₃ₐ to R_{3c} is a group represented by Formula 1-1;
(vii) two of R₁ₐ to R_{1d} are each a group represented by Formula 1-1 and two of R₂ₐ to R_{2d} are each a group represented by Formula 1-1; two of R₁ₐ to R_{1d} are each a group represented by Formula 1-1 and two of R₃ₐ to R_{3c} are each a group represented by Formula 1-1; two of R₂ₐ to R_{2d} are each a group represented by Formula 1-1 and two of R₃ₐ to R_{3c} are each a group represented by Formula 1-1; two of R₁ₐ to R_{1d} are each a group represented by Formula 1-1; one of R₂ₐ to R_{2d} is a group represented by Formula 1-1 and one of R₃ₐ to R_{3c} is a group represented by Formula 1-1; two of R₂ₐ to R_{2d} are each a group represented by Formula 1-1; one of R₁ₐ to R_{1d} is a group represented by Formula 1-1 and one of R₃ₐ to R_{3c} is a group represented by Formula 1-1; two of R₃ₐ to R_{3c} are each a group represented by Formula 1-1, one of R₁ₐ to R_{1d} is a group represented by Formula 1-1, and one of R₂ₐ to R_{2d} is a group represented by Formula 1-1; three of R₁ₐ to R_{1d} are each a group represented by Formula 1-1 and one of R₂ₐ to R_{2d} is a group represented by Formula 1-1; three of R₂ₐ to R_{2d} are each a group represented by Formula 1-1 and one of R₁ₐ to R_{1d} is a group represented by Formula 1-1, three of R₁ₐ to R_{1d} are each a group represented by Formula 1-1 and one of R₃ₐ to R_{3c} is a group represented by Formula 1-1; three of R₂ₐ to R_{2d} are each a group represented by Formula 1-1 and one of R₃ₐ to R_{3c} is a group represented by Formula 1-1; R₃ₐ to R_{3c} are each a group represented by Formula 1-1 and one of R₁ₐ to R_{1d} is a group represented by Formula 1-1; or R₃ₐ to R_{3c} are each a group represented by Formula 1-1 and one of R₂ₐ to R_{2d} is a group represented by Formula 1-1;
(viii) R₁ₐ to R_{1d} are each a group represented by Formula 1-1 and one of R₂ₐ to R_{2d} is a group represented by Formula 1-1; R₁ₐ to R_{1d} are each a group represented by Formula 1-1 and one of R₃ₐ to R_{3c} is a group represented by Formula 1-1; three of R₁ₐ to R_{1d} are each a group represented by Formula 1-1, one of R₂ₐ to R_{2d} is a group represented by Formula 1-1, and one of R₃ₐ to R_{3c} is a group represented by Formula 1-1; three of R₁ₐ to R_{1d} are each a group represented by Formula 1-1 and two of R₂ₐ to R_{2d} are each a group represented by Formula 1-1; three of R₁ₐ to R_{1d} are each a group represented by Formula 1-1 and two of R₃ₐ to R_{3c} are each a group represented by Formula 1-1; two of R₁ₐ to R_{1d} are each a group represented by Formula 1-1 and three of R₂ₐ to R_{2d} are each a group represented by Formula 1-1; two of R₁ₐ to R_{1d} are each a group represented by Formula 1-1, two of R₂ₐ to R_{2d} are each a group represented by Formula 1-1, and one of R₃ₐ to R_{3c} is a group represented by Formula 1-1; two of R₁ₐ to R_{1d} are each a group represented by Formula 1-1, one of R₂ₐ to R_{2d} is a group represented by Formula 1-1, and two of R₃ₐ to R_{3c} are each a group represented by Formula 1-1; two of R₁ₐ to R_{1d} are each a group represented by Formula 1-1 and R₃ₐ to R_{3c} are each a group represented by Formula 1-1; one of R₁ₐ to R_{1d} is a group represented by Formula 1-1 and R₂ₐ to R_{2d} are each a group represented by Formula 1-1; one of R₁ₐ to R_{1d} is a group represented by Formula 1-1, three of R₂ₐ to R_{2d} are each a group represented by Formula 1-1, and one of R₃ₐ to R_{3c} is a group represented by Formula 1-1; one of R₁ₐ to R_{1d} is a group represented by Formula 1-1, two of R₂ₐ to R_{2d} are each a group represented by Formula 1-1, and two of R₃ₐ to R_{3c} are each a group represented by Formula 1-1; one of R₁ₐ to R_{1d} is a group represented by Formula 1-1, one of R₂ₐ to R_{2d} is a group represented by Formula 1-1, and R₃ₐ to R_{3c} are each a group represented by Formula 1-1; R₂ₐ to R_{2d} are each a group represented by Formula 1-1 and one of R₃ₐ to R_{3c} is a group represented by Formula 1-1, three of R₂ₐ to R_{2d} are each a group represented by Formula 1-1, and two of R₃ₐ to R_{3c} are each a group represented by Formula 1-1; or two of R₂ₐ to R_{2d} are each a group represented by Formula 1-1 and R₃ₐ to R_{3c} are each a group represented by Formula 1-1, or
(ix) R₁ₐ to R_{1d} are each a group represented by Formula 1-1 and two of R₂ₐ to R_{2d} are each a group represented by Formula 1-1; R₁ₐ to R_{1d} are each a group represented by Formula 1-1, one of R₂ₐ to R_{2d} is a group represented by Formula 1-1, and one of R₃ₐ to R_{3c} is a group represented by Formula 1-1; R₁ₐ to R_{1d} are each a group represented by Formula 1-1 and two of R₃ₐ to R_{3c} are each a group represented by Formula 1-1; three of R₁ₐ to R_{1d} are each a group represented by Formula 1-1 and three of R₂ₐ to R_{2d} are each a group represented by Formula 1-1; three of R₁ₐ to R_{1d} are each a group represented by Formula 1-1, two of R₂ₐ to R_{2d} are each a group represented by Formula 1-1, and one of R₃ₐ to R_{3c} is a group represented by Formula 1-1; three of R₁ₐ to R_{1d} are each a group represented by Formula 1-1, one of R₂ₐ to R_{2d} is a group represented by Formula 1-1, and two of R₃ₐ to R_{3c} are each a group represented by Formula 1-1; three of R₁ₐ to R_{1d} are each a group represented by Formula 1-1 and R₃ₐ to R_{3c} are each a group represented by Formula 1-1; two of R₁ₐ to R_{1d} are each a group represented by Formula 1-1 and R₂ₐ to R_{2d} are each a group represented by Formula 1-1; two of R₁ₐ to R_{1d} are each a group represented by Formula 1-1, three of R₂ₐ to R_{2d} are each a group represented by Formula 1-1, and one of R₃ₐ to R_{3c} is a group represented by Formula 1-1; two of R₁ₐ to R_{1d} are each a group represented by Formula 1-1, two of R₂ₐ to R_{2d} are each a group represented by Formula 1-1, and two of R₃ₐ to R_{3c} are each a group represented by Formula 1-1; two of R₁ₐ to R_{1d} are each a group represented by Formula 1-1, one of R₂ₐ to R_{2d} is a group represented by Formula 1-1, and R₃ₐ to R₃, are each a group represented by Formula 1-1; one of R₁ₐ to R_{1d} is a group represented by Formula 1-1, R₂ₐ to R_{2d} are each a group represented by Formula 1-1, and one of R₃ₐ to R_{3c} is a group represented by Formula 1-1; one of R₁ₐ to R_{1d} is a group represented by Formula 1-1, three of R₂ₐ to R_{2d} are each a group represented by Formula 1-1, and two of R₃ₐ to R_{3c} are each a group represented by Formula 1-1; one of R₁ₐ to R_{1d} is a group represented by Formula 1-1, two of R₂ₐ to R_{2d} are each a group represented by Formula 1-1, and R₃ₐ to R_{3c} are each a group represented by Formula 1-1; R₂ₐ to R_{2d} are each a group represented by Formula 1-1 and two of R₃ₐ to R_{3c} are each a group represented by Formula 1-1; or three of R₂ₐ to R_{2d} are each a group represented by Formula 1-1 and R₃ₐ to R_{3c} are each a group represented by Formula 1-1.

15. The polycyclic compound of claim 1, wherein Formula 1 is represented by Formula 2A: 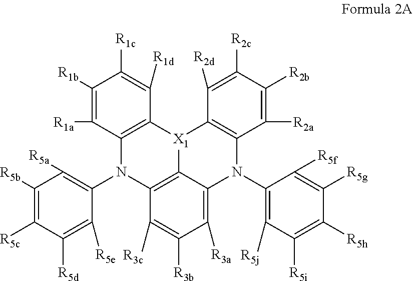
wherein, in Formula 2A,
X₁ is the same as described in claim 1,
R₁ₐ to R_{1d} are each the same as described in connection with R₁ in claim 1, R₂ₐ to R_{2d} are each the same as described in connection with R₂ in claim 1, and
R₃ₐ to R_{3c} are each the same as described in connection with R₃ in claim 1, and R₅ₐ to R₅ⱼ are each the same as described in connection with R₅ in claim 1, and
wherein:
(i) one of R₁ₐ to R_{1d} is a group represented by Formula 1-1; one of R₂ₐ to R_{2d} is a group represented by Formula 1-1; one of R₃ₐ to R_{3c} is a group represented by Formula 1-1; one of R₃ₐ to R₅ₑ is a group represented by Formula 1-1; or one of R_{5f} to R₅ⱼ is a group represented by Formula 1-1,
(ii) two of R₁ₐ to R_{1d} are each a group represented by Formula 1-1; two of R₂ₐ to R_{2d} are each a group represented by Formula 1-1; two of R₃ₐ to R_{3c} are each a group represented by Formula 1-1; two of R₅ₐ to R₅ₑ are each a group represented by Formula 1-1; or two of R_{5f} to R₅ⱼ are each a group represented by Formula 1-1;
(iii) three of R₁ₐ to R_{1d} are each a group represented by Formula 1-1; three of R₂ₐ to R_{2d} are each a group represented by Formula 1-1; each of R₃ₐ to R_{3c} is a group represented by Formula 1-1; three of R₅ₐ to R₅ₑ are each a group represented by Formula 1-1; or three of R_{5f} to R₅ⱼ are each a group represented by Formula 1-1;
(iv) each of R₁ₐ to R_{1d} is a group represented by Formula 1-1; each of R₂ₐ to R_{2d} is a group represented by Formula 1-1; four of R₅ₐ to R₅ₑ are each a group represented by Formula 1-1; or four of R_{5f} to R₅ⱼ are each a group represented by Formula 1-1;
(v) each of R₅ₐ to R₅ₑ is a group represented by Formula 1-1; or each of R_{5f} to R₅ⱼ is a group represented by Formula 1-1;
(vi) one of R₁ₐ to R_{1d} is a group represented by Formula 1-1 and one of R₂ₐ to R_{2d} is a group represented by Formula 1-1; one of R₁ₐ to R_{1d} is a group represented by Formula 1-1 and one of R₃ₐ to R_{3c} is a group represented by Formula 1-1; one of R₁ₐ to R_{1d} is a group represented by Formula 1-1 and one of R₅ₐ to R₅ₑ is a group represented by Formula 1-1; one of R₁ₐ to R_{1d} is a group represented by Formula 1-1 and one of R_{5f} to R₅ⱼ is a group represented by Formula 1-1; one of R₂ₐ to R_{2d} is a group represented by Formula 1-1 and one of R₃ₐ to R_{3c} is a group represented by Formula 1-1; one of R₂ₐ to R_{2d} is a group represented by Formula 1-1 and one of R₃ₐ to R_{3c} is a group represented by Formula 1-1; one of R₂ₐ to R_{2d} is a group represented by Formula 1-1 and one of R_{5f} to R₅ⱼ is a group represented by Formula 1-1; one of R₃ₐ to R_{3c} is a group represented by Formula 1-1 and one of R₅ₐ to R₅ₑ is a group represented by Formula 1-1; one of R₃ₐ to R_{3c} is a group represented by Formula 1-1 and one of R_{5f} to R₅ⱼ is a group represented by Formula 1-1; one of R₅ₐ to R₅ₑ is a group represented by Formula 1-1 and one of R_{5f} to R₅ⱼ is a group represented by Formula 1-1;
(vii) two of R₁ₐ to R_{1d} are each a group represented by Formula 1-1 and one of R₂ₐ to R_{2d} is a group represented by Formula 1-1; two of R₁ₐ to R_{1d} are each a group represented by Formula 1-1 and one of R₃ₐ to R_{3c} is a group represented by Formula 1-1; two of R₁ₐ to R_{1d} are each a group represented by Formula 1-1 and one of R₅ₐ to R₅ₑ is a group represented by Formula 1-1; two of R₁ₐ to R_{1d} are each a group represented by Formula 1-1 and one of R_{5f} to R₅ⱼ is a group represented by Formula 1-1; two of R₂ₐ to R_{2d} are each a group represented by Formula 1-1 and one of R₁ₐ to R_{1d} is a group represented by Formula 1-1; two of R₂ₐ to R_{2d} are each a group represented by Formula 1-1 and one of R₃ₐ to R_{3c} is a group represented by Formula 1-1; two of R₂ₐ to R_{2d} are each a group represented by Formula 1-1 and one of R₅ₐ to R₅ₑ is a group represented by Formula 1-1; two of R₂ₐ to R_{2d} are each a group represented by Formula 1-1 and one of R_{5f} to R₅ⱼ is a group represented by Formula 1-1; two of R₃ₐ to R_{3c} are each a group represented by Formula 1-1 and one of R₁ₐ to R_{1d} is a group represented by Formula 1-1; two of R₃ₐ to R_{3c} are each a group represented by Formula 1-1 and one of R₂ₐ to R_{2d} is a group represented by Formula 1-1; two of R₃ₐ to R_{3c} are each a group represented by Formula 1-1 and one of R₅ₐ to R₅ₑ is a group represented by Formula 1-1; two of R₃ₐ to R_{3c} are each a group represented by Formula 1-1 and one of R_{5f} to R₅ⱼ is a group represented by Formula 1-1; two of R₅ₐ to R₅ₑ are each a group represented by Formula 1-1 and one of R₁ₐ to R_{1d} is a group represented by Formula 1-1; two of R₅ₐ to R₅ₑ are each a group represented by Formula 1-1 and one of R₂ₐ to R_{2d} is a group represented by Formula 1-1; two of R₃ₐ to R_{3c} are each a group represented by Formula 1-1 and one of R₃ₐ to R_{3c} is a group represented by Formula 1-1; two of R₅ₐ to R₅ₑ are each a group represented by Formula 1-1 and one of R_{5f} to R₅ⱼ is a group represented by Formula 1-1; two of R_{5f} to R₅ⱼ are each a group represented by Formula 1-1 and one of R₁ₐ to R_{1d} is a group represented by Formula 1-1; two of R_{5f} to R₅ⱼ are each a group represented by Formula 1-1 and one of R₂ₐ to R_{2d} is a group represented by Formula 1-1; two of R_{5f} to R₅ⱼ are each a group represented by Formula 1-1 and one of R₃ₐ to R_{3c} is a group represented by Formula 1-1; two of R_{5f} to R₅ⱼ are each a group represented by Formula 1-1 and one of R₅ₐ to R₅ₑ is a group represented by Formula 1-1; one of R₁ₐ to R_{1d} is a group represented by Formula 1-1, one of R₂ₐ to R_{2d} is a group represented by Formula 1-1, and one of R₃ₐ to R_{3c} is a group represented by Formula 1-1; one of R₁ₐ to R_{1d} is a group represented by Formula 1-1; one of R₂ₐ to R_{2d} is a group represented by Formula 1-1 and one of R₅ₐ to R₅ₑ is a group represented by Formula 1-1; one of R₁ₐ to R_{1d} is a group represented by Formula 1-1, one of R₂ₐ to R_{2d} is a group represented by Formula 1-1, and one of R_{5f} to R₅ⱼ is a group represented by Formula 1-1; one of R₁ₐ to R_{1d} is a group represented by Formula 1-1, one of R₃ₐ to R_{3c} is a group represented by Formula 1-1, and one of R₅ₐ to R₅ₑ is a group represented by Formula 1-1; one of R₁ₐ to R_{1d} is a group represented by Formula 1-1, one of R₃ₐ to R_{3c} is a group represented by Formula 1-1, and one of R_{5f} to R₅ⱼ is a group represented by Formula 1-1; one of R₁ₐ to R_{1d} is a group represented by Formula 1-1, one of R₅ₐ to R₅ₑ is a group represented by Formula 1-1, and one of R_{5f} to R₅ⱼ is a group represented by Formula 1-1; one of R₂ₐ to R_{2d} is a group represented by Formula 1-1, one of R₃ₐ to R_{3c} is a group represented by Formula 1-1, and one of R₅ₐ to R₅ₑ is a group represented by Formula 1-1; one of R₂ₐ to R_{2d} is a group represented by Formula 1-1, one of R₃ₐ to R_{3c} is a group represented by Formula 1-1, and one of R_{5f} to R₅ⱼ is a group represented by Formula 1-1; one of R₂ₐ to R_{2d} is a group represented by Formula 1-1, one of R₅ₐ to R₅ₑ is a group represented by Formula 1-1, and one of R_{5f} to R₅ⱼ is a group represented by Formula 1-1; or one of R₃ₐ to R_{3c} is a group represented by Formula 1-1, one of R₅ₐ to R₅ₑ is a group represented by Formula 1-1, and one of R_{5f} to R₅ⱼ is a group represented by Formula 1-1;
(viii) two of R₁ₐ to R_{1d} are each a group represented by Formula 1-1 and two of R₂ₐ to R_{2d} are each a group represented by Formula 1-1; two of R₁ₐ to R_{1d} are each a group represented by Formula 1-1 and two of R₃ₐ to R_{3c} are each a group represented by Formula 1-1; two of R₁ₐ to R_{1d} are each a group represented by Formula 1-1 and two of R₃ₐ to R_{3c} are each a group represented by Formula 1-1; two of R₁ₐ to R_{1d} are each a group represented by Formula 1-1 and two of R_{5f} to R₅ⱼ are each a group represented by Formula 1-1; two of R₂ₐ to R_{2d} are each a group represented by Formula 1-1 and two of R₃ₐ to R_{3c} are each a group represented by Formula 1-1; two of R₂ₐ to R_{2d} are each a group represented by Formula 1-1 and two of R₅ₐ to R₅ₑ are each a group represented by Formula 1-1; two of R₂ₐ to R_{2d} are each a group represented by Formula 1-1 and two of R_{5f} to R₅ⱼ are each a group represented by Formula 1-1; two of R₃ₐ to R_{3c} are each a group represented by Formula 1-1 and two of R₅ₐ to R₅ₑ are each a group represented by Formula 1-1; two of R₃ₐ to R_{3c} are each a group represented by Formula 1-1 and two of R_{5f} to R₅ⱼ are each a group represented by Formula 1-1; two of R₅ₐ to R₅ₑ are each a group represented by Formula 1-1 and two of R_{5f} to R₅ⱼ are each a group represented by Formula 1-1; two of R₁ₐ to R_{1d} are each a group represented by Formula 1-1, one of R₂ₐ to R_{2d} is a group represented by Formula 1-1, and one of R₃ₐ to R_{3c} is a group represented by Formula 1-1; two of R₁ₐ to R_{1d} are each a group represented by Formula 1-1, one of R₂ₐ to R_{2d} is a group represented by Formula 1-1, and one of R₅ₐ to R₅ₑ is a group represented by Formula 1-1; two of R₁ₐ to R_{1d} are each a group represented by Formula 1-1, one of R₂ₐ to R_{2d} is a group represented by Formula 1-1, and one of R_{5f} to R₅ⱼ is a group represented by Formula 1-1; two of R₁ₐ to R_{1d} are each a group represented by Formula 1-1, one of R₃ₐ to R_{3c} is a group represented by Formula 1-1, and one of R₅ₐ to R₅ₑ is a group represented by Formula 1-1; two of R₁ₐ to R_{1d} are each a group represented by Formula 1-1, one of R₃ₐ to R_{3c} is a group represented by Formula 1-1, and one of R_{5f} to R₅ⱼ is a group represented by Formula 1-1; two of R₁ₐ to R_{1d} are each a group represented by Formula 1-1, one of R₅ₐ to R₅ₑ is a group represented by Formula 1-1, and one of R_{5f} to R₅ⱼ is a group represented by Formula 1-1; two of R₂ₐ to R_{2d} are each a group represented by Formula 1-1, one of R₁ₐ to R_{1d} is a group represented by Formula 1-1, and one of R₃ₐ to R_{3c} is a group represented by Formula 1-1; two of R₂ₐ to R_{2d} are each a group represented by Formula 1-1, one of R₁ₐ to R_{1d} is a group represented by Formula 1-1, and one of Rₐ to Rₑ is a group represented by Formula 1-1; two of R₂ₐ to R_{2d} are each a group represented by Formula 1-1, one of R₁ₐ to R_{1d} is a group represented by Formula 1-1, and one of R_{5f} to R₅ⱼ is a group represented by Formula 1-1; two of R₂ₐ to R_{2d} are each a group represented by Formula 1-1, one of R₃ₐ to R_{3c} is a group represented by Formula 1-1, and one of Rₐ to Rₑ is a group represented by Formula 1-1; two of R₂ₐ to R_{2d} are each a group represented by Formula 1-1, one of R₃ₐ to R_{3c} is a group represented by Formula 1-1, and one of R_{5f} to R₅ⱼ is a group represented by Formula 1-1; two of R₂ₐ to R_{2d} are each a group represented by Formula 1-1, one of R₃ₐ to R_{3c} is a group represented by Formula 1-1, and one of R_{5f} to R₅ⱼ is a group represented by Formula 1-1; two of R₃ₐ to R_{3c} are each a group represented by Formula 1-1, one of R₁ₐ to R_{1d} is a group represented by Formula 1-1, and one of R₂ₐ to R_{2d} is a group represented by Formula 1-1; two of R₃ₐ to R_{3c} are each a group represented by Formula 1-1, one of R₁ₐ to R_{1d} is a group represented by Formula 1-1, and one of R₅ₐ to R₅ₑ is a group represented by Formula 1-1; two of R₃ₐ to R_{3c} are each a group represented by Formula 1-1, one of R₁ₐ to R_{1d} is a group represented by Formula 1-1, and one of R_{5f} to R₅ⱼ is a group represented by Formula 1-1; two of R₃ₐ to R_{3c} are each a group represented by Formula 1-1, one of R₂ₐ to R_{2d} is a group represented by Formula 1-1, and one of R₅ₐ to R₅ₑ is a group represented by Formula 1-1; two of R₃ₐ to R_{3c} are each a group represented by Formula 1-1, one of R₂ₐ to R_{2d} is a group represented by Formula 1-1, and one of R_{5f} to R₅ⱼ is a group represented by Formula 1-1; two of R₃ₐ to R_{3c} are each a group represented by Formula 1-1, one of R₅ₐ to R₅ₑ is a group represented by Formula 1-1, and one of R_{5f} to R₅ⱼ is a group represented by Formula 1-1; two of R₅ₐ to R₅ₑ are each a group represented by Formula 1-1, one of R₁ₐ to R_{1d} is a group represented by Formula 1-1, and one of R₂ₐ to R_{2d} is a group represented by Formula 1-1; two of R₅ₐ to R₅ₑ are each a group represented by Formula 1-1, one of R₁ₐ to R_{1d} is a group represented by Formula 1-1, and one of R₃ₐ to R_{3c} is a group represented by Formula 1-1; two of R₃ₐ to R_{3c} are each a group represented by Formula 1-1, one of R₁ₐ to R_{1d} is a group represented by Formula 1-1, and one of R_{5f} to R₅ⱼ is a group represented by Formula 1-1; two of R₅ₐ to R₅ₑ are each a group represented by Formula 1-1, one of R₂ₐ to R_{2d} is a group represented by Formula 1-1, and one of R₃ₐ to R_{3c} is a group represented by Formula 1-1; two of R₅ₐ to R₅ₑ are each a group represented by Formula 1-1, one of R₂ₐ to R_{2d} is a group represented by Formula 1-1, and one of R_{5f} to R₅ⱼ is a group represented by Formula 1-1; two of R₅ₐ to R₅ₑ are each a group represented by Formula 1-1, one of R₃ₐ to R_{3c} is a group represented by Formula 1-1, and one of R_{5f} to R₅ⱼ is a group represented by Formula 1-1; two of R_{5f} to R₅ⱼ are each a group represented by Formula 1-1, one of R₁ₐ to R_{1d} is a group represented by Formula 1-1, and one of R₂ₐ to R_{2d} is a group represented by Formula 1-1; two of R_{5f} to R₅ⱼ are each a group represented by Formula 1-1, one of R₁ₐ to R_{1d} is a group represented by Formula 1-1, and one of R₃ₐ to R_{3c} is a group represented by Formula 1-1; two of R_{5f} to R₅ⱼ are each a group represented by Formula 1-1, one of R₁ₐ to R_{1d} is a group represented by Formula 1-1, and one of R₃ₐ to R_{3c} is a group represented by Formula 1-1; two of R_{5f} to R₅ⱼ are each a group represented by Formula 1-1, one of R₂ₐ to R_{2d} is a group represented by Formula 1-1, and one of R₃ₐ to R_{3c} is a group represented by Formula 1-1; two of R_{5f} to R₅ⱼ are each a group represented by Formula 1-1, one of R₂ₐ to R_{2d} is a group represented by Formula 1-1, and one of R₅ₐ to R₅ₑ is a group represented by Formula 1-1; two of R_{5f} to R₅ⱼ are each a group represented by Formula 1-1, one of R₃ₐ to R_{3c} is a group represented by Formula 1-1, and one of R₅ₐ to R₅ₑ is a group represented by Formula 1-1; three of R₁ₐ to R_{1d} are each a group represented by Formula 1-1, and one of R₂ₐ to R_{2d} is a group represented by Formula 1-1; three of R₁ₐ to R_{1d} are each a group represented by Formula 1-1, and one of R₅ₐ to R₅ₑ is a group represented by Formula 1-1; three of R₁ₐ to R_{1d} are each a group represented by Formula 1-1, and one of R_{5f} to R₅ⱼ is a group represented by Formula 1-1; three of R₂ₐ to R_{2d} are each a group represented by Formula 1-1 and one of R₁ₐ to R_{1d} is a group represented by Formula 1-1; three of R₂ₐ to R_{2d} are each a group represented by Formula 1-1 and one of R₅ₐ to R₅ₑ is a group represented by Formula 1-1; three of R₂ₐ to R_{2d} are each a group represented by Formula 1-1 and one of R_{5f} to R₅ⱼ is a group represented by Formula 1-1; three of R₁ₐ to R_{1d} are each a group represented by Formula 1-1 and one of R₃ₐ to R_{3c} is a group represented by Formula 1-1; three of R₂ₐ to R_{2d} are each a group represented by Formula 1-1 and one of R₃ₐ to R_{3c} is a group represented by Formula 1-1; R₃ₐ to R_{3c} are each a group represented by Formula 1-1 and one of R₁ₐ to R_{1d} is a group represented by Formula 1-1; R₃ₐ to R_{3c} are each a group represented by Formula 1-1 and one of R₅ₐ to R₅ₑ is a group represented by Formula 1-1; R₃ₐ to R_{3c} are each a group represented by Formula 1-1 and one of R_{5f} to R₅ⱼ is a group represented by Formula 1-1; R₃ₐ to R_{3c} are each a group represented by Formula 1-1 and one of R₂ₐ to R_{2d} is a group represented by Formula 1-1, three of R₅ₐ to R_{5d} are each a group represented by Formula 1-1, and one of R₁ₐ to R_{1d} is a group represented by Formula 1-1; three of R₅ₐ to R_{5d} are each a group represented by Formula 1-1, and one of R₂ₐ to R_{2d} is a group represented by Formula 1-1; three of R₅ₐ to R_{5d} are each a group represented by Formula 1-1, and one of R₃ₐ to R_{3c} is a group represented by Formula 1-1; or three of R₅ₐ to R_{5d} are each a group represented by Formula 1-1, and one of R_{5f} to R₅ⱼ is a group represented by Formula 1-1;
(ix) R₁ₐ to R_{1d} are each a group represented by Formula 1-1 and one of R₂ₐ to R_{2d} is a group represented by Formula 1-1; R₁ₐ to R_{1d} are each a group represented by Formula 1-1 and one of R₃ₐ to R_{c} is a group represented by Formula 1-1; R₁ₐ to R_{1d} are each a group represented by Formula 1-1 and one of R₅ₐ to R₅ₑ is a group represented by Formula 1-1; R₁ₐ to R_{1d} are each a group represented by Formula 1-1 and one of R_{5f} to R₅ⱼ is a group represented by Formula 1-1; three of R₁ₐ to R_{1d} are each a group represented by Formula 1-1, one of R₂ₐ to R_{2d} is a group represented by Formula 1-1, and one of R₃ₐ to R_{3c} is a group represented by Formula 1-1; three of R₁ₐ to R_{1d} are each a group represented by Formula 1-1, one of R₂ₐ to R_{2d} is a group represented by Formula 1-1, and one of R₅ₐ to R₅ₑ is a group represented by Formula 1-1; three of R₁ₐ to R_{1d} are each a group represented by Formula 1-1, one of R₂ₐ to R_{2d} is a group represented by Formula 1-1, and one of R_{5f} to R₅ⱼ is a group represented by Formula 1-1; three of R₁ₐ to R_{1d} are each a group represented by Formula 1-1, one of R₃ₐ to R_{3c} is a group represented by Formula 1-1, and one of R₅ₐ to R₅ₑ is a group represented by Formula 1-1; three of R₁ₐ to R_{1d} are each a group represented by Formula 1-1, one of R₃ₐ to R_{3c} is a group represented by Formula 1-1, and one of R₅ₐ to R₅ₑ is a group represented by Formula 1-1; three of R₁ₐ to R_{1d} are each a group represented by Formula 1-1, one of R₅ₐ to R₅ₑ is a group represented by Formula 1-1, and one of R_{5f} to R₅ⱼ is a group represented by Formula 1-1; three of R₁ₐ to R_{1d} are each a group represented by Formula 1-1 and two of R₂ₐ to R_{2d} are each a group represented by Formula 1-1; three of R₁ₐ to R_{1d} are each a group represented by Formula 1-1 and two of R₃ₐ to R_{3c} are each a group represented by Formula 1-1; three of R₁ₐ to R_{1d} are each a group represented by Formula 1-1 and two of R₅ₐ to R₅ₑ are each a group represented by Formula 1-1; three of R₁ₐ to R_{1d} are each a group represented by Formula 1-1 and two of R_{5f} to R₅ⱼ are each a group represented by Formula 1-1; two of R₁ₐ to R_{1d} are each a group represented by Formula 1-1 and three of R₂ₐ to R_{2d} are each a group represented by Formula 1-1; two of R₁ₐ to R_{1d} are each a group represented by Formula 1-1, two of R₂ₐ to R_{2d} are each a group represented by Formula 1-1, and one of R₃ₐ to R_{3c} is a group represented by Formula 1-1; two of R₁ₐ to R_{1d} are each a group represented by Formula 1-1, two of R₂ₐ to R_{2d} are each a group represented by Formula 1-1, and one of R₅ₐ to R₅ₑ is a group represented by Formula 1-1; two of R₁ₐ to R_{1d} are each a group represented by Formula 1-1, two of R₂ₐ to R_{2d} are each a group represented by Formula 1-1, and one of R_{5f} to R₅ⱼ is a group represented by Formula 1-1; two of R₁ₐ to R_{1d} are each a group represented by Formula 1-1, one of R₂ₐ to R_{2d} is a group represented by Formula 1-1, and two of R₃ₐ to R_{3c} are each a group represented by Formula 1-1; two of R₁ₐ to R_{1d} are each a group represented by Formula 1-1, one of R₂ₐ to R_{2d} is a group represented by Formula 1-1, and two of R₃ₐ to R_{c} are each a group represented by Formula 1-1; two of R₁ₐ to R_{1d} are each a group represented by Formula 1-1, one of R₂ₐ to R_{2d} is a group represented by Formula 1-1, and two of R_{5f} to R₅ⱼ are each a group represented by Formula 1-1; two of R₁ₐ to R_{1d} are each a group represented by Formula 1-1 and R₃ₐ to R_{3c} are each a group represented by Formula 1-1; two of R₁ₐ to R_{1d} are each a group represented by Formula 1-1 and three of R₅ₐ to R₅ₑ are each a group represented by Formula 1-1; two of R₁ₐ to R_{1d} are each a group represented by Formula 1-1 and three of R_{5f} to R₅ⱼ are each a group represented by Formula 1-1; one of R₁ₐ to R_{1d} is a group represented by Formula 1-1 and R₂ₐ to R_{2d} are each a group represented by Formula 1-1; one of R₁ₐ to R_{1d} is a group represented by Formula 1-1 and four of R₅ₐ to R₅ₑ are each a group represented by Formula 1-1; one of R₁ₐ to R_{1d} is a group represented by Formula 1-1 and four of R_{5f} to R₅ⱼ are each a group represented by Formula 1-1; one of R₁ₐ to R_{1d} is a group represented by Formula 1-1, three of R₂ₐ to R_{2d} are each a group represented by Formula 1-1, and one of R₃ₐ to R_{3c} is a group represented by Formula 1-1; one of R₁ₐ to R_{1d} is a group represented by Formula 1-1, three of R₂ₐ to R_{2d} are each a group represented by Formula 1-1, and one of R₅ₐ to R₅ₑ is a group represented by Formula 1-1; one of R₁ₐ to R_{1d} is a group represented by Formula 1-1, three of R₂ₐ to R_{2d} are each a group represented by Formula 1-1, and one of R_{5f} to R₅ⱼ is a group represented by Formula 1-1; one of R₁ₐ to R_{1d} is a group represented by Formula 1-1, two of R₂ₐ to R_{2d} are each a group represented by Formula 1-1, and two of R₃ₐ to R_{3c} are each a group represented by Formula 1-1; one of R₁ₐ to R_{1d} is a group represented by Formula 1-1, two of R₂ₐ to R_{2d} are each a group represented by Formula 1-1, and two of R_{5f} to R₅ⱼ are each a group represented by Formula 1-1; one of R₁ₐ to R_{1d} is a group represented by Formula 1-1, two of R₂ₐ to R_{2d} are each a group represented by Formula 1-1, and two of R₃ₐ to R_{3c} are each a group represented by Formula 1-1; one of R₁ₐ to R_{1d} is a group represented by Formula 1-1, one of R₂ₐ to R_{2d} is a group represented by Formula 1-1, and R₃ₐ to R_{3c} are each a group represented by Formula 1-1; one of R₁ₐ to R_{1d} is a group represented by Formula 1-1, one of R₂ₐ to R_{2d} is a group represented by Formula 1-1, and three of R₅ₐ to R₅ₑ are each a group represented by Formula 1-1; one of R₁ₐ to R_{1d} is a group represented by Formula 1-1, one of R₂ₐ to R_{2d} is a group represented by Formula 1-1, and three of R_{5f} to R₅ⱼ are each a group represented by Formula 1-1; R₂ₐ to R_{2d} are each a group represented by Formula 1-1 and one of R₃ₐ to R_{3c} is a group represented by Formula 1-1; R₂ₐ to R_{2d} are each a group represented by Formula 1-1 and one of R₅ₐ to R₅ₑ is a group represented by Formula 1-1; R₂ₐ to R_{2d} are each a group represented by Formula 1-1 and one of R_{5f} to R₅ⱼ is a group represented by Formula 1-1; three of R₂ₐ to R_{2d} are each a group represented by Formula 1-1, and two of R₃ₐ to R_{3c} are each a group represented by Formula 1-1; three of R₂ₐ to R_{2d} are each a group represented by Formula 1-1, one of R₃ₐ to R_{3c} is a group represented by Formula 1-1, and one of R₅ₐ to R₅ₑ is a group represented by Formula 1-1; three of R₂ₐ to R_{2d} are each a group represented by Formula 1-1, one of R₃ₐ to R_{3c} is a group represented by Formula 1-1, and one of R_{5f} to R₅ⱼ is a group represented by Formula 1-1; three of R₂ₐ to R_{2d} are each a group represented by Formula 1-1, one of R₅ₐ to R₅ₑ is a group represented by Formula 1-1, and one of R_{5f} to R₅ⱼ is a group represented by Formula 1-1; three of R₂ₐ to R_{2d} are each a group represented by Formula 1-1, and two of R₅ₐ to R₅ⱼ are each a group represented by Formula 1-1; three of R₂ₐ to R_{2d} are each a group represented by Formula 1-1, and two of R_{5f} to R₅ⱼ are each a group represented by Formula 1-1; two of R₂ₐ to R_{2d} are each a group represented by Formula 1-1 and R₃ₐ to R_{3c} are each a group represented by Formula 1-1; two of R₂ₐ to R_{2d} are each a group represented by Formula 1-1, two of R₃ₐ to R_{c} are each a group represented by Formula 1-1 and one of R₃ₐ to R_{3c} is a group represented by Formula 1-1; two of R₂ₐ to R_{2d} are each a group represented by Formula 1-1, two of R₃ₐ to R_{c} are each a group represented by Formula 1-1 and one of R_{5f} to R₅ⱼ is a group represented by Formula 1-1; two of R₂ₐ to R_{2d} are each a group represented by Formula 1-1, one of R₃ₐ to R_{3c} is a group represented by Formula 1-1 and two of R₅ₐ to R₅ₑ are each a group represented by Formula 1-1; two of R₂ₐ to R_{2d} are each a group represented by Formula 1-1, one of R₃ₐ to R_{3c} is a group represented by Formula 1-1 and two of R_{5f} to R₅ⱼ are each a group represented by Formula 1-1; two of R₂ₐ to R_{2d} are each a group represented by Formula 1-1, one of R₃ₐ to R_{3c} is a group represented by Formula 1-1, one of R₅ₐ to R₅ₑ is a group represented by Formula 1-1 and one of R_{5f} to R₅ⱼ is a group represented by Formula 1-1; two of R₂ₐ to R_{2d} are each a group represented by Formula 1-1 and three of R₅ₐ to R₅ⱼ are each a group represented by Formula 1-1; two of R₂ₐ to R_{2d} are each a group represented by Formula 1-1, two of R_{5f} to R₅ⱼ are each a group represented by Formula 1-1 and one of R_{5f} to R₅ⱼ is a group represented by Formula 1-1; two of R₂ₐ to R_{2d} are each a group represented by Formula 1-1, one of R₅ₐ to R₅ₑ is a group represented by Formula 1-1 and two of R_{5f} to R₅ⱼ are each a group represented by Formula 1-1; two of R₂ₐ to R_{2d} are each a group represented by Formula 1-1 and three of R_{5f} to R₅ⱼ are each a group represented by Formula 1-1; one of R₂ₐ to R_{2d} is a group represented by Formula 1-1, three of R₃ₐ to R_{3c} are each a group represented by Formula 1-1 and one of R₃ₐ to R_{3c} is a group represented by Formula 1-1; one of R₂ₐ to R_{2d} is a group represented by Formula 1-1, three of R₃ₐ to R_{3c} are each a group represented by Formula 1-1 and one of R_{5f} to R₅ⱼ are each a group represented by Formula 1-1; one of R₂ₐ to R_{2d} is a group represented by Formula 1-1, two of R₃ₐ to R_{3c} are each a group represented by Formula 1-1 and two of R₅ₐ to R₅ₑ are each a group represented by Formula 1-1; one of R₂ₐ to R_{2d} is a group represented by Formula 1-1, two of R₃ₐ to R_{3c} are each a group represented by Formula 1-1 and two of R_{5f} to R₅ⱼ are each a group represented by Formula 1-1; one of R₂ₐ to R_{2d} is a group represented by Formula 1-1, one of R₃ₐ to R_{3c} is a group represented by Formula 1-1 and three of R₅ₐ to R₅ₑ are each a group represented by Formula 1-1; one of R₂ₐ to R_{2d} is a group represented by Formula 1-1, one of R₃ₐ to R_{3c} is a group represented by Formula 1-1 and three of R_{5f} to R₅ⱼ are each a group represented by Formula 1-1; one of R₂ₐ to R_{2d} is a group represented by Formula 1-1 and four of R₅ₐ to R₅ₑ are each a group represented by Formula 1-1; one of R₂ₐ to R_{2d} is a group represented by Formula 1-1 and four of R_{5f} to R₅ⱼ are each a group represented by Formula 1-1; one of R₂ₐ to R_{2d} is a group represented by Formula 1-1, three of R₅ₐ to R₅ₑ are each a group represented by Formula 1-1 and one of R_{5f} to R₅ⱼ is a group represented by Formula 1-1; one of R₂ₐ to R_{2d} is a group represented by Formula 1-1, two of R₅ₐ to R₅ₑ are each a group represented by Formula 1-1 and two of R_{5f} to R₅ⱼ are each a group represented by Formula 1-1; one of R₂ₐ to R_{2d} is a group represented by Formula 1-1, one of R₅ₐ to R₅ₑ is a group represented by Formula 1-1 and three of R_{5f} to R₅ⱼ are each a group represented by Formula 1-1; R₃ₐ to R_{3c} are each a group represented by Formula 1-1 and two of R₃ₐ to R_{3c} are each a group represented by Formula 1-1; R₃ₐ to R_{3c} are each a group represented by Formula 1-1 and two of R_{5f} to R₅ⱼ are each a group represented by Formula 1-1; R₃ₐ to R_{3c} are each a group represented by Formula 1-1, one of R₃ₐ to R_{3c} is a group represented by Formula 1-1 and one of R_{5f} to R₅ⱼ is a group represented by Formula 1-1; two of R₃ₐ to R_{3c} are each a group represented by Formula 1-1 and three of Rₐ to Rₑ are each a group represented by Formula 1-1; two of R₃ₐ to R_{3c} are each a group represented by Formula 1-1 and three of R_{5f} to R₅ⱼ are each a group represented by Formula 1-1; two of R₃ₐ to R_{3c} are each a group represented by Formula 1-1, two of R₅ₐ to R₅ₑ are each a group represented by Formula 1-1, one of R_{5f} to R₅ⱼ is a group represented by Formula 1-1; two of R₃ₐ to R_{3c} are each a group represented by Formula 1-1, one of R₅ₐ to R₅ₑ is a group represented by Formula 1-1, two of R_{5f} to R₅ⱼ are each a group represented by Formula 1-1; one of R₃ₐ to R_{3c} is a group represented by Formula 1-1, four of R₃ₐ to R_{3c} are each a group represented by Formula 1-1; one of R₃ₐ to R_{3c} is a group represented by Formula 1-1, four of R_{5f} to R₅ⱼ are each a group represented by Formula 1-1; one of R₃ₐ to R_{3c} is a group represented by Formula 1-1, three of R₅ₐ to R₅ₑ are each a group represented by Formula 1-1 and one of R_{5f} to R₅ⱼ is a group represented by Formula 1-1; one of R₃ₐ to R_{3c} is a group represented by Formula 1-1, two of R₅ₐ to R₅ₑ are each a group represented by Formula 1-1 and two of R_{5f} to R₅ⱼ are each a group represented by Formula 1-1; one of R₃ₐ to R_{3c} is a group represented by Formula 1-1, one of R₅ₐ to R₅ₑ is a group represented by Formula 1-1 and three of R_{5f} to R₅ⱼ are each a group represented by Formula 1-1; R₅ₐ to R₅ₑ are each a group represented by Formula 1-1; R_{5f} to R₅ⱼ are each a group represented by Formula 1-1; four of R₅ₐ to R₅ₑ are each a group represented by Formula 1-1 and one of R_{5f} to R₅ⱼ is a group represented by Formula 1-1; three of R₅ₐ to R₅ₑ are each a group represented by Formula 1-1 and two of R_{5f} to R₅ⱼ are each a group represented by Formula 1-1; two of Rₐ to Rₑ are each a group represented by Formula 1-1 and three of R_{5f} to R₅ⱼ are each a group represented by Formula 1-1; one of R₅ₐ to R₅ₑ is a group represented by Formula 1-1 and four of R_{5f} to R₅ⱼ are each a group represented by Formula 1-1; or
(x) R₁ₐ to R_{1d} are each a group represented by Formula 1-1 and two of R₂ₐ to R_{2d} are each a group represented by Formula 1-1; R₁ₐ to R_{1d} are each a group represented by Formula 1-1, one of R₂ₐ to R_{2d} is a group represented by Formula 1-1, and one of R₃ₐ to R_{3c} is a group represented by Formula 1-1; R₁ₐ to R_{1d} are each a group represented by Formula 1-1 and two of R₃ₐ to R_{3c} are each a group represented by Formula 1-1; R₁ₐ to R_{1d} are each a group represented by Formula 1-1 and two of R₅ₐ to R₅ₑ are each a group represented by Formula 1-1; R₁ₐ to R_{1d} are each a group represented by Formula 1-1 and two of R_{5f} to R₅ⱼ are each a group represented by Formula 1-1; R₁ₐ to R_{1d} are each a group represented by Formula 1-1 one of R₂ₐ to R_{2d} is a group represented by Formula 1-1 and one of R₅ₐ to R₅ₑ is a group represented by Formula 1-1; R₁ₐ to R_{1d} are each a group represented by Formula 1-1, one of R₂ₐ to R_{2d} is a group represented by Formula 1-1 and one of R_{5f} to R₅ⱼ is a group represented by Formula 1-1; R₁ₐ to R_{1d} are each a group represented by Formula 1-1, one of R₃ₐ to R_{3c} is a group represented by Formula 1-1 and one of R₅ₐ to R₅ₑ is a group represented by Formula 1-1; R₁ₐ to R_{1d} are each a group represented by Formula 1-1, one of R₃ₐ to R_{3c} is a group represented by Formula 1-1 and one of R_{5f} to R₅ⱼ is a group represented by Formula 1-1; R₁ₐ to R_{1d} are each a group represented by Formula 1-1, one of R₅ₐ to R₅ₑ is a group represented by Formula 1-1 and one of R_{5f} to R₅ⱼ is a group represented by Formula 1-1; three of R₁ₐ to R_{1d} are each a group represented by Formula 1-1 and three of R₂ₐ to R_{2d} are each a group represented by Formula 1-1; three of R₁ₐ to R_{1d} are each a group represented by Formula 1-1, two of R₂ₐ to R_{2d} are each a group represented by Formula 1-1, and one of R₃ₐ to R_{3c} is a group represented by Formula 1-1; three of R₁ₐ to R_{1d} are each a group represented by Formula 1-1, two of R₂ₐ to R_{2d} are each a group represented by Formula 1-1, and one of R₅ₐ to R₅ₑ is a group represented by Formula 1-1; three of R₁ₐ to R_{1d} are each a group represented by Formula 1-1, two of R₂ₐ to R_{2d} are each a group represented by Formula 1-1, and one of R_{5f} to R₅ⱼ is a group represented by Formula 1-1; three of R₁ₐ to R_{1d} are each a group represented by Formula 1-1, one of R₂ₐ to R_{2d} is a group represented by Formula 1-1, and two of R₃ₐ to R_{3c} are each a group represented by Formula 1-1; three of R₁ₐ to R_{1d} are each a group represented by Formula 1-1, one of R₂ₐ to R_{2d} is a group represented by Formula 1-1, and two of R₅ₐ to R₅ₑ are each a group represented by Formula 1-1; three of R₁ₐ to R_{1d} are each a group represented by Formula 1-1, one of R₂ₐ to R_{2d} is a group represented by Formula 1-1, and two of R_{5f} to R₅ⱼ are each a group represented by Formula 1-1; three of R₁ₐ to R_{1d} are each a group represented by Formula 1-1, one of R₂ₐ to R_{2d} is a group represented by Formula 1-1, one of R₅ₐ to R₅ₑ is a group represented by Formula 1-1 and one of R_{5f} to R₅ⱼ is a group represented by Formula 1-1; three of R₁ₐ to R_{1d} are each a group represented by Formula 1-1 and R₃ₐ to R_{3c} are each a group represented by Formula 1-1; three of R₁ₐ to R_{1d} are each a group represented by Formula 1-1 and two of R₃ₐ to R_{3c} are each a group represented by Formula 1-1 and one of R_{5f} to R₅ⱼ is a group represented by Formula 1-1; three of R₁ₐ to R_{1d} are each a group represented by Formula 1-1 and two of R₃ₐ to R_{3c} are each a group represented by Formula 1-1 and one of R_{5f} to R₅ⱼ is a group represented by Formula 1-1; three of R₁ₐ to R_{1d} are each a group represented by Formula 1-1, one of R₃ₐ to R_{3c} is a group represented by Formula 1-1 and two of R₅ₐ to R₅ₑ are each a group represented by Formula 1-1; three of R₁ₐ to R_{1d} are each a group represented by Formula 1-1, one of R₃ₐ to R_{3c} is a group represented by Formula 1-1 and two of R_{5f} to R₅ⱼ are each a group represented by Formula 1-1; three of R₁ₐ to R_{1d} are each a group represented by Formula 1-1, one of R₃ₐ to R_{3c} is a group represented by Formula 1-1, one of R₅ₐ to R₅ₑ is a group represented by Formula 1-1 and one of R_{5f} to R₅ⱼ is a group represented by Formula 1-1; two of R₁ₐ to R_{1d} are each a group represented by Formula 1-1 and R₂ₐ to R_{2d} are each a group represented by Formula 1-1; two of R₁ₐ to R_{1d} are each a group represented by Formula 1-1, three of R₂ₐ to R_{2d} are each a group represented by Formula 1-1, and one of R₃ₐ to R_{3c} is a group represented by Formula 1-1; two of R₁ₐ to R_{1d} are each a group represented by Formula 1-1, three of R₂ₐ to R_{2d} are each a group represented by Formula 1-1, and one of R₅ₐ to R₅ₑ is a group represented by Formula 1-1; two of R₁ₐ to R_{1d} are each a group represented by Formula 1-1, three of R₂ₐ to R_{2d} are each a group represented by Formula 1-1, and one of R_{5f} to R₅ⱼ is a group represented by Formula 1-1; two of R₁ₐ to R_{1d} are each a group represented by Formula 1-1, two of R₂ₐ to R_{2d} are each a group represented by Formula 1-1, and two of R₃ₐ to R_{3c} are each a group represented by Formula 1-1; two of R₁ₐ to R_{1d} are each a group represented by Formula 1-1, two of R₂ₐ to R_{2d} are each a group represented by Formula 1-1, one of R₃ₐ to R_{3c} is a group represented by Formula 1-1 and one of R₃ₐ to R_{3c} is a group represented by Formula 1-1; two of R₁ₐ to R_{1d} are each a group represented by Formula 1-1, two of R₂ₐ to R_{2d} are each a group represented by Formula 1-1, one of R₃ₐ to R_{3c} is a group represented by Formula 1-1 and one of R_{5f} to R₅ⱼ is a group represented by Formula 1-1; two of R₁ₐ to R_{1d} are each a group represented by Formula 1-1, two of R₂ₐ to R_{2d} are each a group represented by Formula 1-1, one of R₅ₐ to R₅ₑ is a group represented by Formula 1-1 and one of R_{5f} to R₅ⱼ is a group represented by Formula 1-1; two of R₁ₐ to R_{1d} are each a group represented by Formula 1-1, one of R₂ₐ to R_{2d} is a group represented by Formula 1-1, and R₃ₐ to R_{3c} are each a group represented by Formula 1-1; two of R₁ₐ to R_{1d} are each a group represented by Formula 1-1, one of R₂ₐ to R_{2d} is a group represented by Formula 1-1, and R₃ₐ to R_{3c} are each a group represented by Formula 1-1; two of R₁ₐ to R_{1d} are each a group represented by Formula 1-1, one of R₂ₐ to R_{2d} is a group represented by Formula 1-1, two of R₃ₐ to R_{3c} are each a group represented by Formula 1-1 and one of R₅ₐ to R₅ₑ is a group represented by Formula 1-1; two of R₁ₐ to R_{1d} are each a group represented by Formula 1-1, one of R₂ₐ to R_{2d} is a group represented by Formula 1-1, two of R₃ₐ to R_{3c} are each a group represented by Formula 1-1 and one of R_{5f} to R₅ⱼ is a group represented by Formula 1-1; two of R₁ₐ to R_{1d} are each a group represented by Formula 1-1, one of R₂ₐ to R_{2d} is a group represented by Formula 1-1, one of R₃ₐ to R_{3c} is a group represented by Formula 1-1 and two of R₅ₐ to R₅ₑ are each a group represented by Formula 1-1; two of R₁ₐ to R_{1d} are each a group represented by Formula 1-1, one of R₂ₐ to R_{2d} is a group represented by Formula 1-1, one of R₃ₐ to R_{3c} is a group represented by Formula 1-1 and two of R_{5f} to R₅ⱼ are each a group represented by Formula 1-1; two of R₁ₐ to R_{1d} are each a group represented by Formula 1-1, one of R₂ₐ to R_{2d} is a group represented by Formula 1-1, one of R₃ₐ to R_{3c} is a group represented by Formula 1-1, one of R₅ₐ to R₅ₑ is a group represented by Formula 1-1 and one of R_{5f} to R₅ⱼ is a group represented by Formula 1-1; two of R₁ₐ to R_{1d} are each a group represented by Formula 1-1, one of R₂ₐ to R_{2d} is a group represented by Formula 1-1, and three of R₅ₐ to R₅ₑ are each a group represented by Formula 1-1; two of R₁ₐ to R_{1d} are each a group represented by Formula 1-1, one of R₂ₐ to R_{2d} is a group represented by Formula 1-1, two of R₅ₐ to R₅ⱼ are each a group represented by Formula 1-1 and one of R_{5f} to R₅ⱼ is a group represented by Formula 1-1; two of R₁ₐ to R_{1d} are each a group represented by Formula 1-1, one of R₂ₐ to R_{2d} is a group represented by Formula 1-1, one of R₅ₐ to R₅ₑ is a group represented by Formula 1-1 and two of R_{5f} to R₅ⱼ are each a group represented by Formula 1-1; two of R₁ₐ to R_{1d} are each a group represented by Formula 1-1, one of R₂ₐ to R_{2d} is a group represented by Formula 1-1 and three of R_{5f} to R₅ⱼ are each a group represented by Formula 1-1; one of R₁ₐ to R_{1d} is a group represented by Formula 1-1, R₂ₐ to R_{2d} are each a group represented by Formula 1-1, and one of R₃ₐ to R_{3c} is a group represented by Formula 1-1; one of R₁ₐ to R_{1d} is a group represented by Formula 1-1, R₂ₐ to R_{2d} are each a group represented by Formula 1-1, and one of R₅ₐ to R₅ₑ is a group represented by Formula 1-1; one of R₁ₐ to R_{1d} is a group represented by Formula 1-1, R₂ₐ to R_{2d} are each a group represented by Formula 1-1, and one of R_{5f} to R₅ⱼ is a group represented by Formula 1-1; one of R₁ₐ to R_{1d} is a group represented by Formula 1-1, three of R₂ₐ to R_{2d} are each a group represented by Formula 1-1, and two of R₃ₐ to R_{3c} are each a group represented by Formula 1-1; one of R₁ₐ to R_{1d} is a group represented by Formula 1-1, three of R₂ₐ to R_{2d} are each a group represented by Formula 1-1, one of R₃ₐ to R_{3c} is a group represented by Formula 1-1 and one of R₅ₐ to R₅ₑ is a group represented by Formula 1-1; one of R₁ₐ to R_{1d} is a group represented by Formula 1-1, three of R₂ₐ to R_{2d} are each a group represented by Formula 1-1, one of R₃ₐ to R_{3c} is a group represented by Formula 1-1 and one of R_{5f} to R₅ⱼ is a group represented by Formula 1-1; one of R₁ₐ to R_{1d} is a group represented by Formula 1-1, three of R₂ₐ to R_{2d} are each a group represented by Formula 1-1, two of Rₐ to Rₑ are each a group represented by Formula 1-1; one of R₁ₐ to R_{1d} is a group represented by Formula 1-1, three of R₂ₐ to R_{2d} are each a group represented by Formula 1-1, one of R₅ₐ to R₅ₑ is a group represented by Formula 1-1 and one of R_{5f} to R₅ⱼ is a group represented by Formula 1-1; one of R₁ₐ to R_{1d} is a group represented by Formula 1-1, three of R₂ₐ to R_{2d} are each a group represented by Formula 1-1 and two of R_{5f} to R₅ⱼ is a group represented by Formula 1-1; one of R₁ₐ to R_{1d} is a group represented by Formula 1-1, two of R₂ₐ to R_{2d} are each a group represented by Formula 1-1, and R₃ₐ to R_{3c} are each a group represented by Formula 1-1; one of R₁ₐ to R_{1d} is a group represented by Formula 1-1, two of R₂ₐ to R_{2d} are each a group represented by Formula 1-1, two of R₃ₐ to R_{3c} are each a group represented by Formula 1-1, one of R₅ₐ to R₅ₑ is a group represented by Formula 1-1; one of R₁ₐ to R_{1d} is a group represented by Formula 1-1, two of R₂ₐ to R_{2d} are each a group represented by Formula 1-1, two of R₃ₐ to R_{3c} are each a group represented by Formula 1-1, one of R_{5f} to R₅ⱼ is a group represented by Formula 1-1; one of R₁ₐ to R_{1d} is a group represented by Formula 1-1, two of R₂ₐ to R_{2d} are each a group represented by Formula 1-1, one of R₃ₐ to R_{c} is a group represented by Formula 1-1, two of R₅ₐ to R₅ₑ are each a group represented by Formula 1-1; one of R₁ₐ to R_{1d} is a group represented by Formula 1-1, two of R₂ₐ to R_{2d} are each a group represented by Formula 1-1, one of R₃ₐ to R_{3c} is a group represented by Formula 1-1, one of R₅ₐ to R₅ₑ is a group represented by Formula 1-1 and one of R_{5f} to R₅ⱼ is a group represented by Formula 1-1; one of R₁ₐ to R_{1d} is a group represented by Formula 1-1, two of R₂ₐ to R_{2d} are each a group represented by Formula 1-1, one of R₃ₐ to R_{3c} is a group represented by Formula 1-1 and two of R_{5f} to R₅ⱼ is a group represented by Formula 1-1; one of R₁ₐ to R_{1d} is a group represented by Formula 1-1, two of R₂ₐ to R_{2d} are each a group represented by Formula 1-1, and three of R₅ₐ to R₅ₑ are each a group represented by Formula 1-1; one of R₁ₐ to R_{1d} is a group represented by Formula 1-1, two of R₂ₐ to R_{2d} are each a group represented by Formula 1-1, two of R₅ₐ to R₅ₑ are each a group represented by Formula 1-1 and one of R_{5f} to R₅ⱼ is a group represented by Formula 1-1; one of R₁ₐ to R_{1d} is a group represented by Formula 1-1, two of R₂ₐ to R_{2d} are each a group represented by Formula 1-1, one of R₅ₐ to R₅ₑ is a group represented by Formula 1-1 and two of R_{5f} to R₅ⱼ are each a group represented by Formula 1-1; one of R₁ₐ to R_{1d} is a group represented by Formula 1-1, two of R₂ₐ to R_{2d} are each a group represented by Formula 1-1 and three of R_{5f} to R₅ⱼ are each a group represented by Formula 1-1; one of R₁ₐ to R_{1d} is a group represented by Formula 1-1, one of R₂ₐ to R_{2d} is a group represented by Formula 1-1, R₃ₐ to R_{3c} are each a group represented by Formula 1-1 and one of R₅ₐ to R₅ₑ is a group represented by Formula 1-1; one of R₁ₐ to R_{1d} is a group represented by Formula 1-1, one of R₂ₐ to R_{2d} are each a group represented by Formula 1-1, R₃ₐ to R_{3c} are each a group represented by Formula 1-1 and one of R_{5f} to R₅ⱼ is a group represented by Formula 1-1; one of R₁ₐ to R_{1d} is a group represented by Formula 1-1, one of R₂ₐ to R_{2d} is a group represented by Formula 1-1, two of R₃ₐ to R_{3c} are each a group represented by Formula 1-1 and two of R₅ₐ to R₅ₑ are each a group represented by Formula 1-1; one of R₁ₐ to R_{1d} is a group represented by Formula 1-1, one of R₂ₐ to R_{2d} is a group represented by Formula 1-1, two of R₃ₐ to R_{3c} are each a group represented by Formula 1-1 and two of R_{5f} to R₅ⱼ are each a group represented by Formula 1-1; one of R₁ₐ to R_{1d} is a group represented by Formula 1-1, one of R₂ₐ to R_{2d} is a group represented by Formula 1-1, two of R₃ₐ to R_{3c} are each a group represented by Formula 1-1, one of R₅ₐ to R₅ₑ is a group represented by Formula 1-1 and one of R_{5f} to R₅ⱼ is a group represented by Formula 1-1; one of R₁ₐ to R_{1d} is a group represented by Formula 1-1, one of R₂ₐ to R_{2d} is a group represented by Formula 1-1, one of R₃ₐ to R_{3c} is a group represented by Formula 1-1 and three of R₅ₐ to R₅ₑ are each a group represented by Formula 1-1; one of R₁ₐ to R_{1d} is a group represented by Formula 1-1, one of R₂ₐ to R_{2d} is a group represented by Formula 1-1, one of R₃ₐ to R_{3c} is a group represented by Formula 1-1, two of R₅ₐ to R₅ₑ are each a group represented by Formula 1-1 and one of R_{5f} to R₅ⱼ is a group represented by Formula 1-1; one of R₁ₐ to R_{1d} is a group represented by Formula 1-1, one of R₂ₐ to R_{2d} is a group represented by Formula 1-1, one of R₃ₐ to R_{3c} is a group represented by Formula 1-1, one of R₅ₐ to R₅ₑ is a group represented by Formula 1-1 and two of R_{5f} to R₅ⱼ are each a group represented by Formula 1-1; one of R₁ₐ to R_{1d} is a group represented by Formula 1-1, one of R₂ₐ to R_{2d} is a group represented by Formula 1-1, one of R₃ₐ to R_{3c} is a group represented by Formula 1-1 and three of R_{5f} to R₅ⱼ are each a group represented by Formula 1-1; one of R₁ₐ to R_{1d} is a group represented by Formula 1-1, one of R₂ₐ to R_{2d} is a group represented by Formula 1-1 and four of R₅ₐ to R₅ₑ are each a group represented by Formula 1-1; one of R₁ₐ to R_{1d} is a group represented by Formula 1-1, one of R₂ₐ to R_{2d} is a group represented by Formula 1-1, three of R₅ₐ to R₅ₑ are each a group represented by Formula 1-1, one of R_{5f} to R₅ⱼ is a group represented by Formula 1-1; one of R₁ₐ to R_{1d} is a group represented by Formula 1-1, one of R₂ₐ to R_{2d} is a group represented by Formula 1-1, two of R₅ₐ to R₅ₑ are each a group represented by Formula 1-1, two of R_{5f} to R₅ⱼ are each a group represented by Formula 1-1; one of R₁ₐ to R_{1d} is a group represented by Formula 1-1, one of R₂ₐ to R_{2d} is a group represented by Formula 1-1, one of R₅ₐ to R₅ₑ is a group represented by Formula 1-1 and three of R_{5f} to R₅ⱼ are each a group represented by Formula 1-1; one of R₁ₐ to R_{1d} is a group represented by Formula 1-1, one of R₂ₐ to R_{2d} is a group represented by Formula 1-1 and four of R_{5f} to R₅ⱼ are each a group represented by Formula 1-1; one of R₁ₐ to R_{1d} is a group represented by Formula 1-1, R₃ₐ to R_{3c} are each a group represented by Formula 1-1, two of R₅ₐ to R₅ₑ are each a group represented by Formula 1-1; one of R₁ₐ to R_{1d} is a group represented by Formula 1-1, R₃ₐ to R_{3c} are each a group represented by Formula 1-1, one of R₅ₐ to R₅ₑ is a group represented by Formula 1-1 and one of R_{5f} to R₅ⱼ is a group represented by Formula 1-1; one of R₁ₐ to R_{1d} is a group represented by Formula 1-1, R₃ₐ to R_{3c} are each a group represented by Formula 1-1 and two of R_{5f} to R₅ⱼ are each a group represented by Formula 1-1; one of R₁ₐ to R_{1d} is a group represented by Formula 1-1, two of R₃ₐ to R_{3c} are each a group represented by Formula 1-1 and three of R₅ₐ to R₅ₑ are each a group represented by Formula 1-1; one of R₁ₐ to R_{1d} is a group represented by Formula 1-1, two of R₃ₐ to R_{3c} are each a group represented by Formula 1-1, two of R₅ₐ to R₅ₑ are each a group represented by Formula 1-1 and one of R_{5f} to R₅ⱼ is a group represented by Formula 1-1; one of R₁ₐ to R_{1d} is a group represented by Formula 1-1, two of R₃ₐ to R_{3c} are each a group represented by Formula 1-1, one of R₅ₐ to R₅ₑ is a group represented by Formula 1-1 and two of R_{5f} to R₅ⱼ are each a group represented by Formula 1-1; one of R₁ₐ to R_{1d} is a group represented by Formula 1-1, two of R₃ₐ to R_{3c} are each a group represented by Formula 1-1 and three of R_{5f} to R₅ⱼ are each a group represented by Formula 1-1; one of R₁ₐ to R_{1d} is a group represented by Formula 1-1, one of R₃ₐ to R_{3c} is a group represented by Formula 1-1 and four of R₃ₐ to R_{3c} are each a group represented by Formula 1-1; one of R₁ₐ to R_{1d} is a group represented by Formula 1-1, one of R₃ₐ to R_{3c} is a group represented by Formula 1-1, three of R₅ₐ to R₅ₑ are each a group represented by Formula 1-1 and one of R_{5f} to R₅ⱼ are each a group represented by Formula 1-1; one of R₁ₐ to R_{1d} is a group represented by Formula 1-1, one of R₃ₐ to R_{3c} is a group represented by Formula 1-1, two of R₅ₐ to R₅ₑ are each a group represented by Formula 1-1 and two of R_{5f} to R₅ⱼ are each a group represented by Formula 1-1; one of R₁ₐ to R_{1d} is a group represented by Formula 1-1, one of R₃ₐ to R_{3c} is a group represented by Formula 1-1, one of R₅ₐ to R₅ₑ is a group represented by Formula 1-1 and three of R_{5f} to R₅ⱼ are each a group represented by Formula 1-1; one of R₁ₐ to R_{1d} is a group represented by Formula 1-1, one of R₃ₐ to R_{3c} is a group represented by Formula 1-1 and four of R_{5f} to R₅ⱼ are each a group represented by Formula 1-1; one of R₁ₐ to R_{1d} is a group represented by Formula 1-1 and R₅ₐ to R₅ₑ are each a group represented by Formula 1-1; one of R₁ₐ to R_{1d} is a group represented by Formula 1-1, four of R₅ₐ to R₅ₑ are each a group represented by Formula 1-1 and one of R_{5f} to R₅ⱼ is a group represented by Formula 1-1; one of R₁ₐ to R_{1d} is a group represented by Formula 1-1, three of R₅ₐ to R₅ₑ are each a group represented by Formula 1-1 and two of R_{5f} to R₅ⱼ are each a group represented by Formula 1-1; one of R₁ₐ to R_{1d} is a group represented by Formula 1-1, two of R₅ₐ to R₅ₑ are each a group represented by Formula 1-1 and three of R_{5f} to R₅ⱼ are each a group represented by Formula 1-1; one of R₁ₐ to R_{1d} is a group represented by Formula 1-1, one of R₅ₐ to R₅ₑ is a group represented by Formula 1-1 and four of R_{5f} to R₅ⱼ are each a group represented by Formula 1-1; one of R₁ₐ to R_{1d} is a group represented by Formula 1-1 and R_{5f} to R₅ⱼ are each a group represented by Formula 1-1; R₂ₐ to R_{2d} are each a group represented by Formula 1-1 and two of R₃ₐ to R_{3c} are each a group represented by Formula 1-1; R₂ₐ to R_{2d} are each a group represented by Formula 1-1, one of R₃ₐ to R_{3c} are each a group represented by Formula 1-1 and one of R₅ₐ to R₅ₑ is a group represented by Formula 1-1; R₂ₐ to R_{2d} are each a group represented by Formula 1-1, one of R₃ₐ to R_{3c} are each a group represented by Formula 1-1 and one of R_{5f} to R₅ⱼ is a group represented by Formula 1-1; R₂ₐ to R_{2d} are each a group represented by Formula 1-1 and two of R₅ₐ to R₅ₑ are each a group represented by Formula 1-1; R₂ₐ to R_{2d} are each a group represented by Formula 1-1, one of R₅ₐ to R₅ₑ is a group represented by Formula 1-1 and one of R_{5f} to R₅ⱼ is a group represented by Formula 1-1; R₂ₐ to R_{2d} are each a group represented by Formula 1-1 and two of R_{5f} to R₅ⱼ are each a group represented by Formula 1-1; three of R₂ₐ to R_{2d} are each a group represented by Formula 1-1 and R₃ₐ to R_{3c} are each a group represented by Formula 1-1; three of R₂ₐ to R_{2d} are each a group represented by Formula 1-1, two of R₃ₐ to R_{3c} are each a group represented by Formula 1-1 and one of R₅ₐ to R₅ₑ is a group represented by Formula 1-1; three of R₂ₐ to R_{2d} are each a group represented by Formula 1-1, two of R₃ₐ to R_{3c} are each a group represented by Formula 1-1 and one of R_{5f} to R₅ⱼ is a group represented by Formula 1-1; three of R₂ₐ to R_{2d} are each a group represented by Formula 1-1, one of R₃ₐ to R_{3c} is a group represented by Formula 1-1 and two of R₅ₐ to R₅ₑ are each a group represented by Formula 1-1; three of R₂ₐ to R_{2d} are each a group represented by Formula 1-1, one of R₃ₐ to R_{3c} is a group represented by Formula 1-1, one of R₅ₐ to R₅ₑ is a group represented by Formula 1-1 and one of R_{5f} to R₅ⱼ is a group represented by Formula 1-1; three of R₂ₐ to R_{2d} are each a group represented by Formula 1-1, one of R₃ₐ to R_{3c} is a group represented by Formula 1-1 and two of R_{5f} to R₅ⱼ are each a group represented by Formula 1-1; three of R₂ₐ to R_{2d} are each a group represented by Formula 1-1 and three of R₅ₐ to R₅ₑ are each a group represented by Formula 1-1; three of R₂ₐ to R_{2d} are each a group represented by Formula 1-1, two of R₅ₐ to R₅ₑ are each a group represented by Formula 1-1 and one of R_{5f} to R₅ⱼ is a group represented by Formula 1-1; three of R₂ₐ to R_{2d} are each a group represented by Formula 1-1, one of R₅ₐ to R₅ₑ is a group represented by Formula 1-1 and two of R_{5f} to R₅ⱼ are each a group represented by Formula 1-1; three of R₂ₐ to R_{2d} are each a group represented by Formula 1-1 and three of R_{5f} to R₅ⱼ are each a group represented by Formula 1-1; two of R₂ₐ to R_{2d} are each a group represented by Formula 1-1, R₃ₐ to R_{3c} are each a group represented by Formula 1-1 and one of R₅ₐ to R₅ₑ is a group represented by Formula 1-1; two of R₂ₐ to R_{2d} are each a group represented by Formula 1-1, R₃ₐ to R_{3c} are each a group represented by Formula 1-1 and one of R_{5f} to R₅ⱼ is a group represented by Formula 1-1; two of R₂ₐ to R_{2d} are each a group represented by Formula 1-1, two of R₃ₐ to R_{3c} are each a group represented by Formula 1-1 and two of R₅ₐ to R₅ₑ are each a group represented by Formula 1-1; two of R₂ₐ to R_{2d} are each a group represented by Formula 1-1, two of R₃ₐ to R_{3c} are each a group represented by Formula 1-1, one of R₅ₐ to R₅ₑ is a group represented by Formula 1-1 and one of R_{5f} to R₅ⱼ is a group represented by Formula 1-1; two of R₂ₐ to R_{2d} are each a group represented by Formula 1-1, two of R₃ₐ to R_{3c} are each a group represented by Formula 1-1 and two of R_{5f} to R₅ⱼ are each a group represented by Formula 1-1; two of R₂ₐ to R_{2d} are each a group represented by Formula 1-1, one of R₃ₐ to R_{3c} is a group represented by Formula 1-1 and three of R₃ₐ to R_{3c} are each a group represented by Formula 1-1; two of R₂ₐ to R_{2d} are each a group represented by Formula 1-1, one of R₃ₐ to R_{3c} is a group represented by Formula 1-1, two of R₅ₐ to R₅ₑ are each a group represented by Formula 1-1 and one of R_{5f} to R₅ⱼ is a group represented by Formula 1-1; two of R₂ₐ to R_{2d} are each a group represented by Formula 1-1, one of R₃ₐ to R_{3c} is a group represented by Formula 1-1, one of R₅ₐ to R₅ₑ is a group represented by Formula 1-1 and two of R_{5f} to R₅ⱼ are each a group represented by Formula 1-1; two of R₂ₐ to R_{2d} are each a group represented by Formula 1-1, one of R₃ₐ to R_{3c} is a group represented by Formula 1-1 and three of R_{5f} to R₅ⱼ are each a group represented by Formula 1-1; two of R₂ₐ to R_{2d} are each a group represented by Formula 1-1 and four of R₅ₐ to R₅ₑ are each a group represented by Formula 1-1; two of R₂ₐ to R_{2d} are each a group represented by Formula 1-1, three of R₅ₐ to R₅ₑ are each a group represented by Formula 1-1 and one of R_{5f} to R₅ⱼ is a group represented by Formula 1-1; two of R₂ₐ to R_{2d} are each a group represented by Formula 1-1, two of R₅ₐ to R₅ₑ are each a group represented by Formula 1-1 and two of R_{5f} to R₅ⱼ are each a group represented by Formula 1-1; two of R₂ₐ to R_{2d} are each a group represented by Formula 1-1, one of R₅ₐ to R₅ₑ is a group represented by Formula 1-1 and three of R_{5f} to R₅ⱼ are each a group represented by Formula 1-1; two of R₂ₐ to R_{2d} are each a group represented by Formula 1-1 and four of R_{5f} to R₅ⱼ are each a group represented by Formula 1-1; one of R₂ₐ to R_{2d} is a group represented by Formula 1-1, R₃ₐ to R_{3c} are each a group represented by Formula 1-1 and two of R₅ₐ to R₅ₑ are each a group represented by Formula 1-1; one of R₂ₐ to R_{2d} is a group represented by Formula 1-1, R₃ₐ to R_{3c} are each a group represented by Formula 1-1, one of R₅ₐ to R₅ₑ is a group represented by Formula 1-1 and one of R_{5f} to R₅ⱼ is a group represented by Formula 1-1; one of R₂ₐ to R_{2d} is a group represented by Formula 1-1, R₃ₐ to R_{3c} are each a group represented by Formula 1-1 and two of R_{5f} to R₅ⱼ are each a group represented by Formula 1-1; one of R₂ₐ to R_{2d} is a group represented by Formula 1-1, two of R₃ₐ to R_{3c} are each a group represented by Formula 1-1 and three of R₅ₐ to R₅ₑ are each a group represented by Formula 1-1; one of R₂ₐ to R_{2d} is a group represented by Formula 1-1, two of R₃ₐ to R_{3c} are each a group represented by Formula 1-1, two of R₃ₐ to R_{3c} are each a group represented by Formula 1-1 and one of R_{5f} to R₅ⱼ is each a group represented by Formula 1-1; one of R₂ₐ to R_{2d} is a group represented by Formula 1-1, two of R₃ₐ to R_{3c} are each a group represented by Formula 1-1, one of R₅ₐ to R₅ₑ is a group represented by Formula 1-1 and two of R_{5f} to R₅ⱼ are each a group represented by Formula 1-1; one of R₂ₐ to R_{2d} is a group represented by Formula 1-1, two of R₃ₐ to R_{3c} are each a group represented by Formula 1-1 and three of R_{5f} to R₅ⱼ are each a group represented by Formula 1-1; one of R₂ₐ to R_{2d} is a group represented by Formula 1-1, one of R₃ₐ to R_{3c} is a group represented by Formula 1-1 and four of R₅ₐ to R₅ₑ are each a group represented by Formula 1-1; one of R₂ₐ to R_{2d} is a group represented by Formula 1-1, one of R₃ₐ to R_{3c} is a group represented by Formula 1-1, three of R₅ₐ to R₅ₑ are each a group represented by Formula 1-1 and one of R_{5f} to R₅ⱼ is a group represented by Formula 1-1; one of R₂ₐ to R_{2d} is a group represented by Formula 1-1, one of R₃ₐ to R_{c} is a group represented by Formula 1-1, two of R₅ₐ to R₅ₑ are each a group represented by Formula 1-1 and two of R_{5f} to R₅ⱼ are each a group represented by Formula 1-1; one of R₂ₐ to R_{2d} is a group represented by Formula 1-1, one of R₃ₐ to R_{3c} is a group represented by Formula 1-1, one of R₅ₐ to R₅ₑ is a group represented by Formula 1-1 and three of R_{5f} to R₅ⱼ are each a group represented by Formula 1-1; one of R₂ₐ to R_{2d} is a group represented by Formula 1-1, one of R₃ₐ to R_{3c} is a group represented by Formula 1-1 and four of R_{5f} to R₅ⱼ are each a group represented by Formula 1-1; one of R₂ₐ to R_{2d} is a group represented by Formula 1-1, and R₅ₐ to R₅ₑ are each a group represented by Formula 1-1; one of R₂ₐ to R_{2d} is a group represented by Formula 1-1, and R_{5f} to R₅ⱼ are each a group represented by Formula 1-1; R₃ₐ to R_{3c} are each a group represented by Formula 1-1 and three of R₅ₐ to R₅ₑ are each a group represented by Formula 1-1; R₃ₐ to R_{3c} are each a group represented by Formula 1-1, two of R₅ₐ to R₅ₑ are each a group represented by Formula 1-1 and one of R_{5f} to R₅ⱼ is a group represented by Formula 1-1; R₃ₐ to R_{3c} are each a group represented by Formula 1-1, one of R₅ₐ to R₅ₑ is a group represented by Formula 1-1 and two of R_{5f} to R₅ⱼ are each a group represented by Formula 1-1; R₃ₐ to R_{3c} are each a group represented by Formula 1-1 and three of R_{5f} to R₅ⱼ are each a group represented by Formula 1-1; two of R₃ₐ to R_{3c} are each a group represented by Formula 1-1 and four of R₅ₐ to R₅ₑ are each a group represented by Formula 1-1; two of R₃ₐ to R_{3c} are each a group represented by Formula 1-1, three of R₅ₐ to R₅ₑ are each a group represented by Formula 1-1 and one of R_{5f} to R₅ⱼ is a group represented by Formula 1-1; two of R₃ₐ to R_{3c} are each a group represented by Formula 1-1, two of R₅ₐ to R₅ₑ are each a group represented by Formula 1-1 and two of R_{5f} to R₅ⱼ are each a group represented by Formula 1-1; two of R₃ₐ to R_{3c} are each a group represented by Formula 1-1, one of R₅ₐ to R₅ₑ is a group represented by Formula 1-1 and three of R_{5f} to R₅ⱼ are each a group represented by Formula 1-1; two of R₃ₐ to R_{3c} are each a group represented by Formula 1-1 and four of R_{5f} to R₅ⱼ are each a group represented by Formula 1-1; one of R₃ₐ to R_{3c} is a group represented by Formula 1-1 and R₅ₐ to R₅ₑ are each a group represented by Formula 1-1; one of R₃ₐ to R_{3c} is a group represented by Formula 1-1 and R_{5f} to R₅ⱼ are each a group represented by Formula 1-1; R₅ₐ to R₅ₑ are each a group represented by Formula 1-1 and one of R_{5f} to R₅ⱼ is a group represented by Formula 1-1; four of R₅ₐ to R₅ₑ are each a group represented by Formula 1-1 and two of R_{5f} to R₅ⱼ are each a group represented by Formula 1-1; three of R₅ₐ to R₅ₑ are each a group represented by Formula 1-1 and three of R_{5f} to R₅ⱼ are each a group represented by Formula 1-1; two of R₅ₐ to R₅ₑ are each a group represented by Formula 1-1 and four of R_{5f} to R₅ⱼ are each a group represented by Formula 1-1; or one of R₅ₐ to R₅ₑ is a group represented by Formula 1-1 and R_{5f} to R₅ⱼ are each a group represented by Formula 1-1.

16. The polycyclic compound of claim 1, wherein the polycyclic compound represented by Formula 1 is one of Compounds 1 to 107:

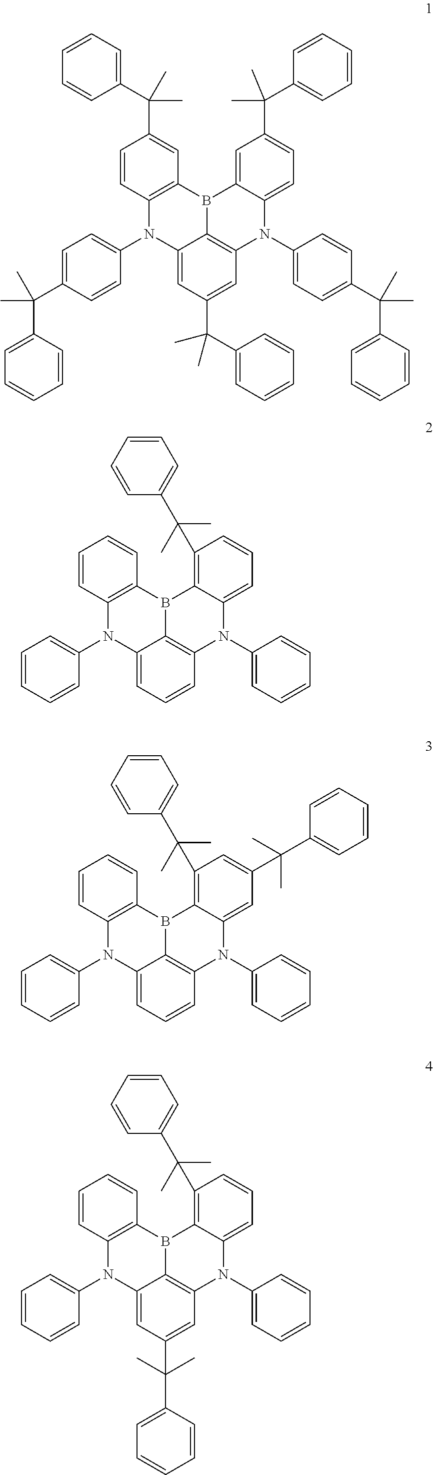 [SMILES: CC(C)(c1ccccc1)c1ccc(N2c3ccc(C(C)(C)c4ccccc4)cc3B3c4cc(C(C)(C)c5ccccc5)ccc4N(c4ccc(C(C)(C)c5ccccc5)cc4)c4cc(C(C)(C)c5ccccc5)cc2c43)cc1 ; CC(C)(c1ccccc1)c1cccc2c1B1c3ccccc3N(c3ccccc3)c3cccc(c31)N2c1ccccc1 ; CC(C)(c1ccccc1)c1cc2c(c(C(C)(C)c3ccccc3)c1)B1c3ccccc3N(c3ccccc3)c3cccc(c31)N2c1ccccc1 ; CC(C)(c1ccccc1)c1cc2c3c(c1)N(c1ccccc1)c1cccc(C(C)(C)c4ccccc4)c1B3c1ccccc1N2c1ccccc1]

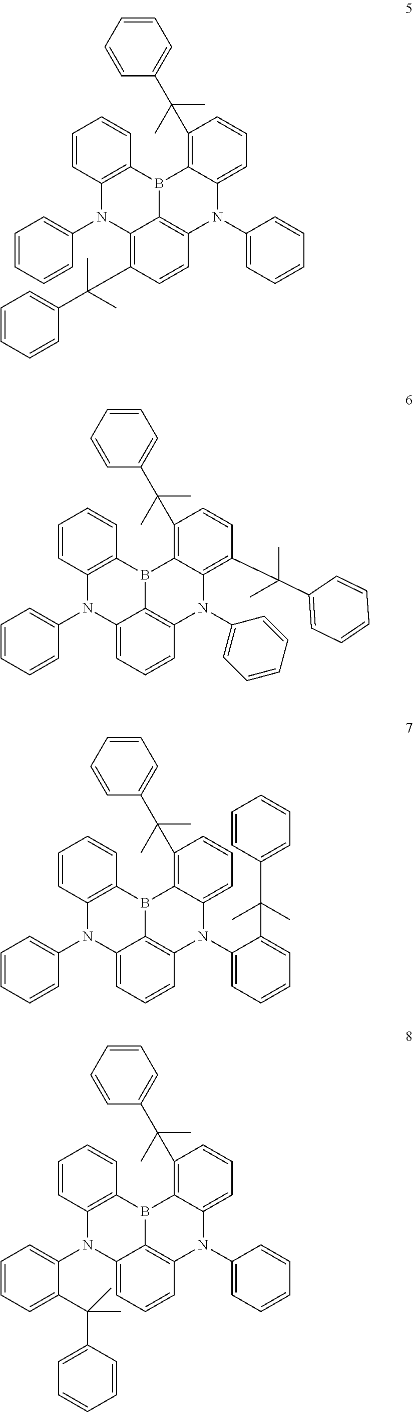

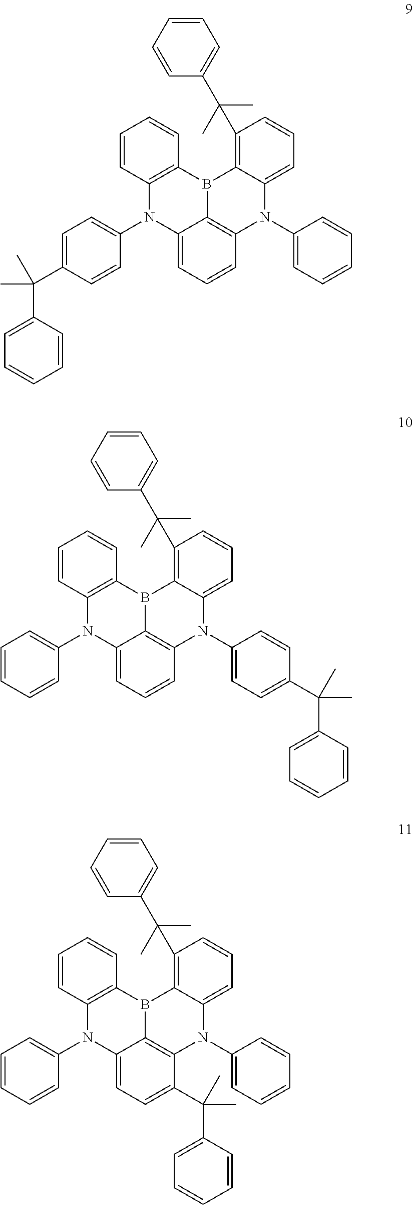 [SMILES: CC(C)(c1ccccc1)c1ccc(N2c3ccccc3B3c4c2cccc4N(c2ccccc2)c2cccc(C(C)(C)c4ccccc4)c23)cc1 ; CC(C)(c1ccccc1)c1ccc(N2c3cccc4c3B(c3ccccc3N4c3ccccc3)c3c2cccc3C(C)(C)c2ccccc2)cc1 ; CC(C)(c1ccccc1)c1cccc2c1B1c3ccccc3N(c3ccccc3)c3ccc(C(C)(C)c4ccccc4)c(c31)N2c1ccccc1]

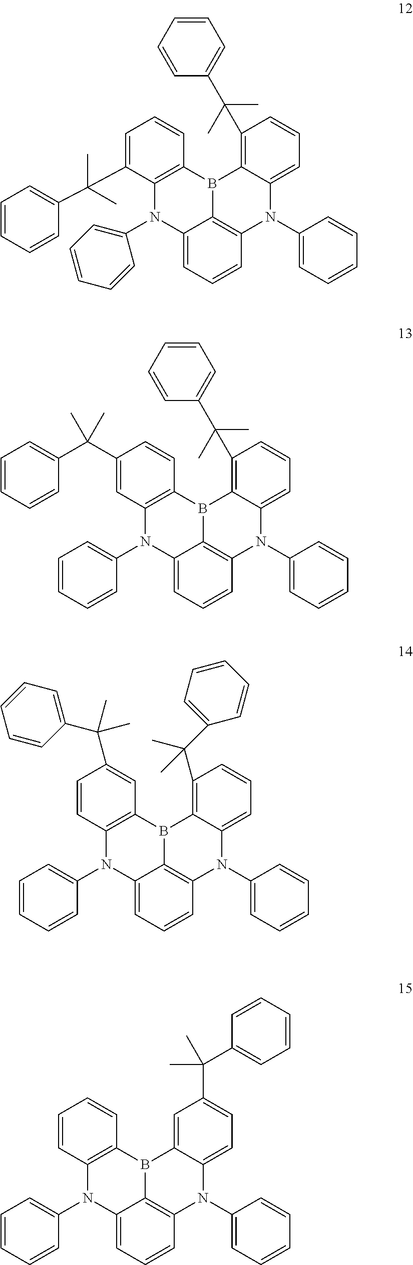 [SMILES: CC(C)(c1ccccc1)c1cccc2c1B1c3cccc(C(C)(C)c4ccccc4)c3N(c3ccccc3)c3cccc(c31)N2c1ccccc1 ; CC(C)(c1ccccc1)c1ccc2c(c1)N(c1ccccc1)c1cccc3c1B2c1c(cccc1C(C)(C)c1ccccc1)N3c1ccccc1 ; CC(C)(c1ccccc1)c1ccc2c(c1)B1c3c(cccc3N(c3ccccc3)c3cccc(C(C)(C)c4ccccc4)c31)N2c1ccccc1 ; CC(C)(c1ccccc1)c1ccc2c(c1)B1c3ccccc3N(c3ccccc3)c3cccc(c31)N2c1ccccc1]

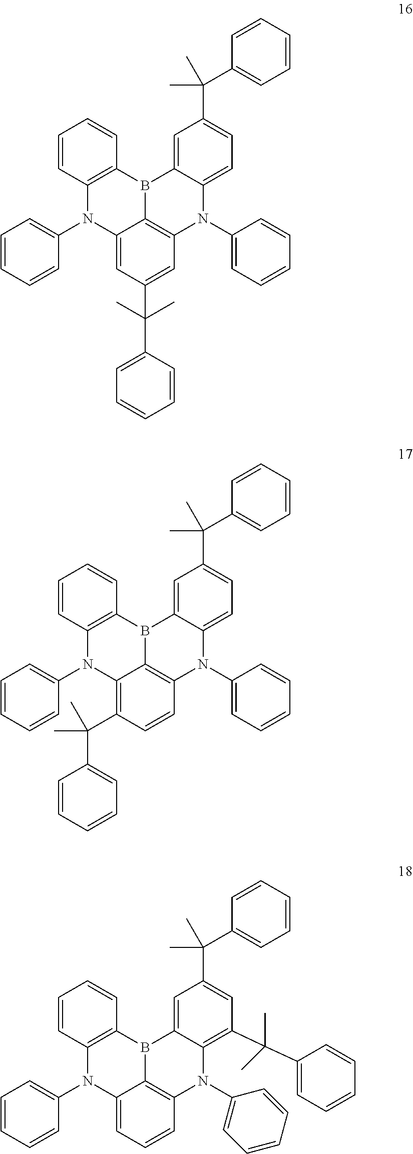 [SMILES: CC(C)(c1ccccc1)c1ccc2c(c1)B1c3ccccc3N(c3ccccc3)c3cc(C(C)(C)c4ccccc4)cc(c31)N2c1ccccc1 ; CC(C)(c1ccccc1)c1ccc2c(c1)B1c3ccccc3N(c3ccccc3)c3c(C(C)(C)c4ccccc4)ccc(c31)N2c1ccccc1 ; CC(C)(c1ccccc1)c1cc2c(c(C(C)(C)c3ccccc3)c1)N(c1ccccc1)c1cccc3c1B2c1ccccc1N3c1ccccc1]

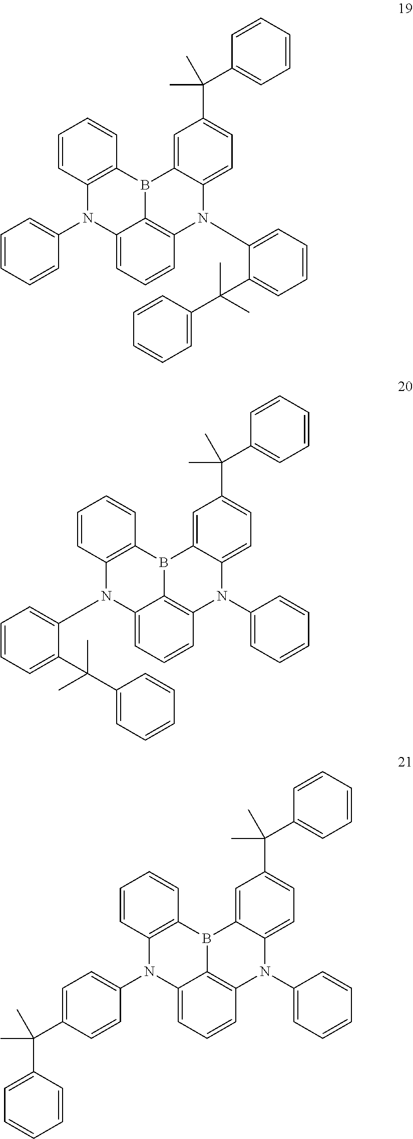 [SMILES: CC(C)(c1ccccc1)c1ccc2c(c1)B1c3ccccc3N(c3ccccc3)c3cccc(c31)N2c1ccccc1C(C)(C)c1ccccc1 ; CC(C)(c1ccccc1)c1ccc2c(c1)B1c3ccccc3N(c3ccccc3C(C)(C)c3ccccc3)c3cccc(c31)N2c1ccccc1 ; CC(C)(c1ccccc1)c1ccc(N2c3ccccc3B3c4cc(C(C)(C)c5ccccc5)ccc4N(c4ccccc4)c4cccc2c43)cc1]

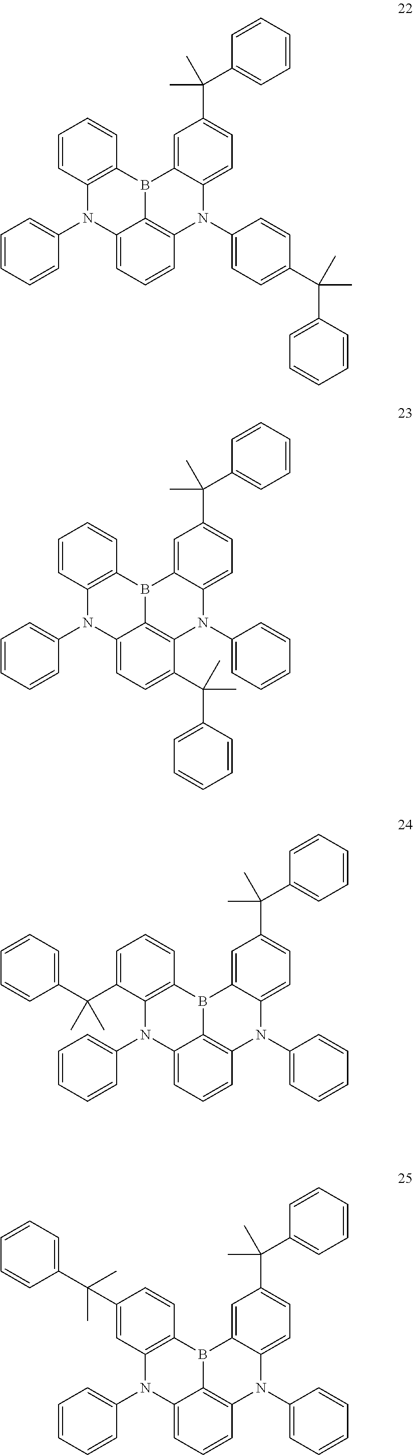 [SMILES: CC(C)(c1ccccc1)c1ccc(N2c3ccc(C(C)(C)c4ccccc4)cc3B3c4ccccc4N(c4ccccc4)c4cccc2c43)cc1 ; CC(C)(c1ccccc1)c1ccc2c(c1)B1c3ccccc3N(c3ccccc3)c3ccc(C(C)(C)c4ccccc4)c(c31)N2c1ccccc1 ; CC(C)(c1ccccc1)c1ccc2c(c1)B1c3cccc(C(C)(C)c4ccccc4)c3N(c3ccccc3)c3cccc(c31)N2c1ccccc1 ; CC(C)(c1ccccc1)c1ccc2c(c1)B1c3ccc(C(C)(C)c4ccccc4)cc3N(c3ccccc3)c3cccc(c31)N2c1ccccc1]

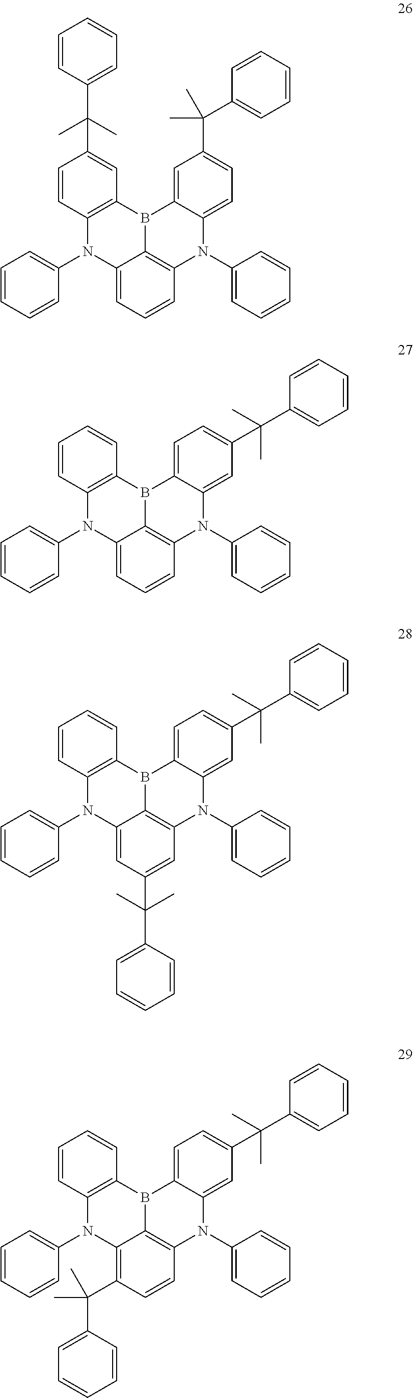 [SMILES: CC(C)(c1ccccc1)c1ccc2c(c1)B1c3cc(C(C)(C)c4ccccc4)ccc3N(c3ccccc3)c3cccc(c31)N2c1ccccc1 ; CC(C)(c1ccccc1)c1ccc2c(c1)N(c1ccccc1)c1cccc3c1B2c1ccccc1N3c1ccccc1 ; CC(C)(c1ccccc1)c1ccc2c(c1)N(c1ccccc1)c1cc(C(C)(C)c3ccccc3)cc3c1B2c1ccccc1N3c1ccccc1 ; CC(C)(c1ccccc1)c1ccc2c(c1)N(c1ccccc1)c1ccc(C(C)(C)c3ccccc3)c3c1B2c1ccccc1N3c1ccccc1]

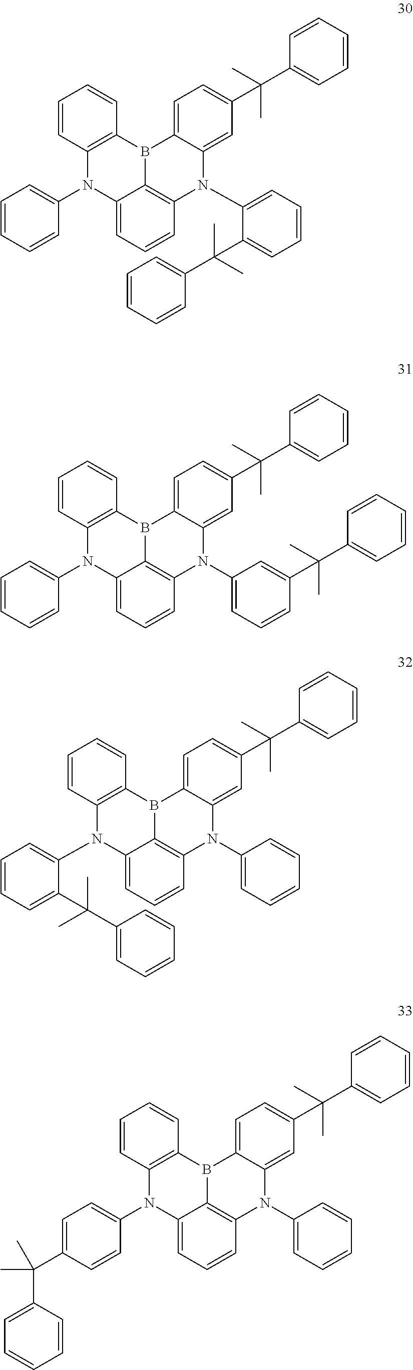 [SMILES: CC(C)(c1ccccc1)c1ccc2c(c1)N(c1ccccc1C(C)(C)c1ccccc1)c1cccc3c1B2c1ccccc1N3c1ccccc1 ; CC(C)(c1ccccc1)c1cccc(N2c3cc(C(C)(C)c4ccccc4)ccc3B3c4ccccc4N(c4ccccc4)c4cccc2c43)c1 ; CC(C)(c1ccccc1)c1ccc2c(c1)N(c1ccccc1)c1cccc3c1B2c1ccccc1N3c1ccccc1C(C)(C)c1ccccc1 ; CC(C)(c1ccccc1)c1ccc(N2c3ccccc3B3c4ccc(C(C)(C)c5ccccc5)cc4N(c4ccccc4)c4cccc2c43)cc1]

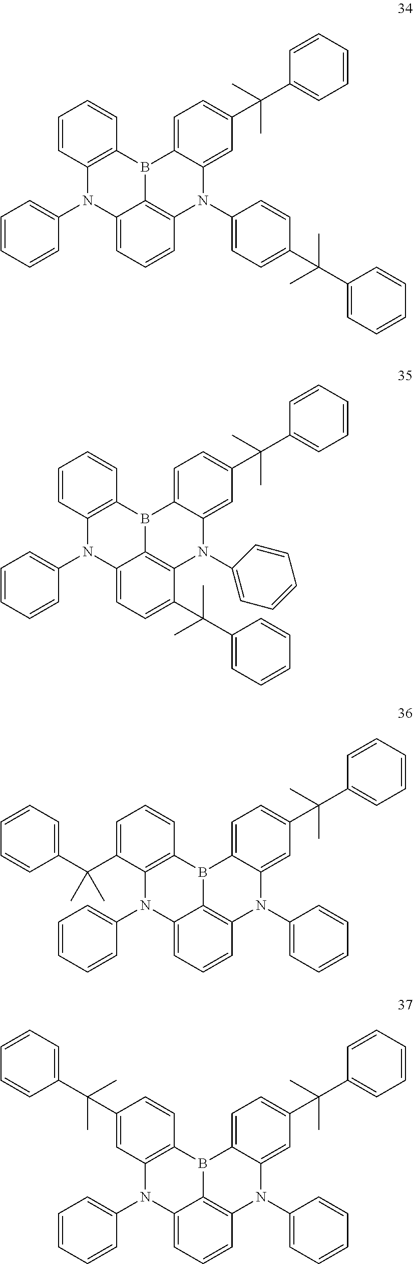 [SMILES: CC(C)(c1ccccc1)c1ccc(N2c3cc(C(C)(C)c4ccccc4)ccc3B3c4ccccc4N(c4ccccc4)c4cccc2c43)cc1 ; CC(C)(c1ccccc1)c1ccc2c(c1)N(c1ccccc1)c1c(C(C)(C)c3ccccc3)ccc3c1B2c1ccccc1N3c1ccccc1 ; CC(C)(c1ccccc1)c1ccc2c(c1)N(c1ccccc1)c1cccc3c1B2c1cccc(C(C)(C)c2ccccc2)c1N3c1ccccc1 ; CC(C)(c1ccccc1)c1ccc2c(c1)N(c1ccccc1)c1cccc3c1B2c1ccc(C(C)(C)c2ccccc2)cc1N3c1ccccc1]

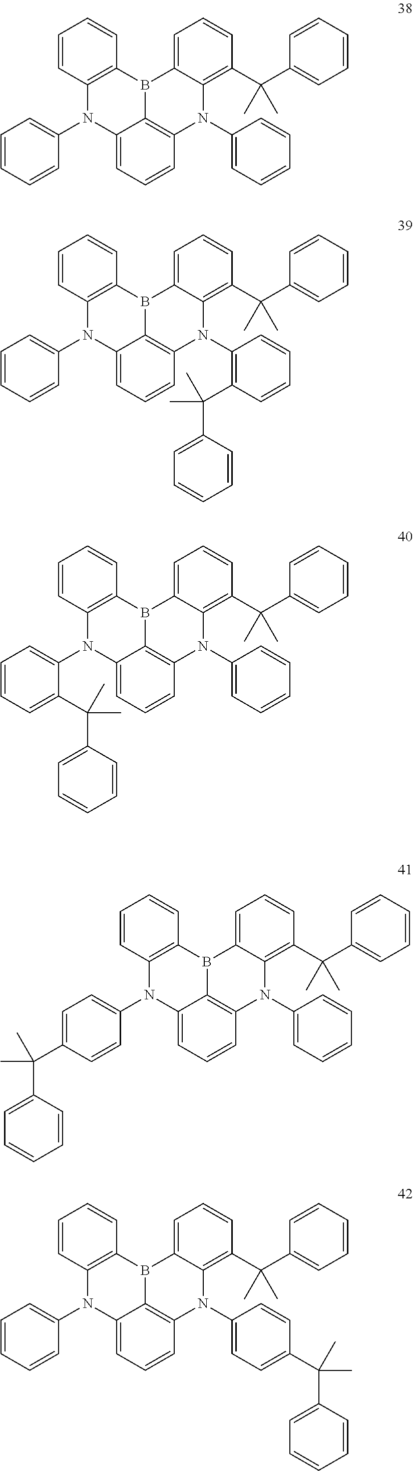

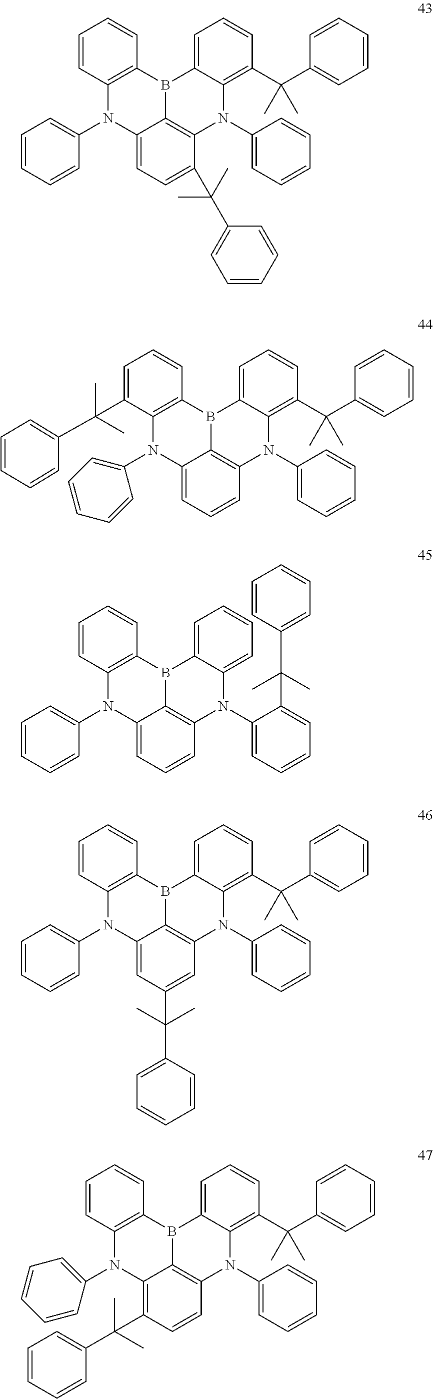 [SMILES: CC(C)(c1ccccc1)c1cccc2c1N(c1ccccc1)c1c(C(C)(C)c3ccccc3)ccc3c1B2c1ccccc1N3c1ccccc1 ; CC(C)(c1ccccc1)c1cccc2c1N(c1ccccc1)c1cccc3c1B2c1cccc(C(C)(C)c2ccccc2)c1N3c1ccccc1 ; CC(C)(c1ccccc1)c1ccccc1N1c2ccccc2B2c3ccccc3N(c3ccccc3)c3cccc1c32 ; CC(C)(c1ccccc1)c1cc2c3c(c1)N(c1ccccc1)c1c(cccc1C(C)(C)c1ccccc1)B3c1ccccc1N2c1ccccc1 ; CC(C)(c1ccccc1)c1cccc2c1N(c1ccccc1)c1ccc(C(C)(C)c3ccccc3)c3c1B2c1ccccc1N3c1ccccc1]

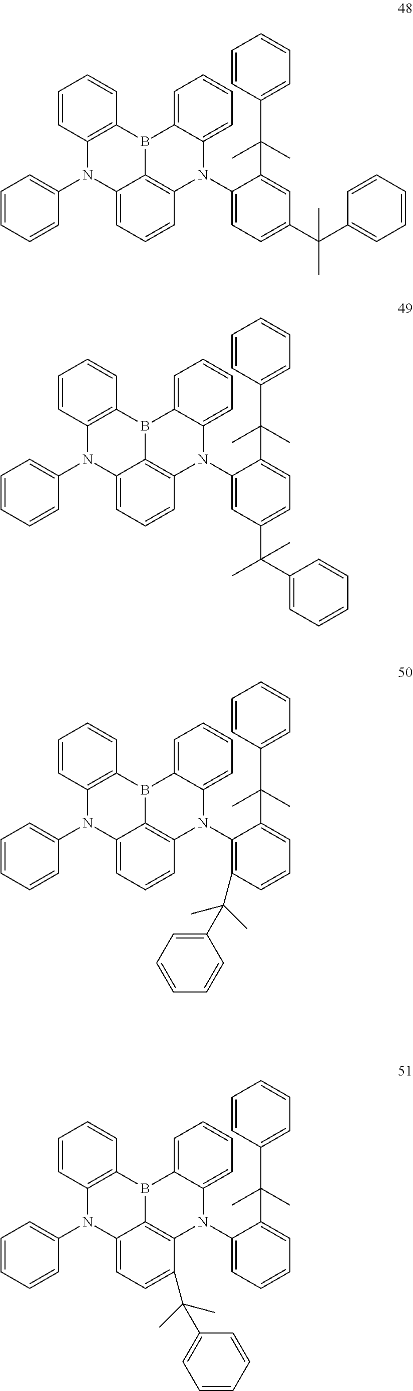 [SMILES: CC(C)(c1ccccc1)c1ccc(N2c3ccccc3B3c4ccccc4N(c4ccccc4)c4cccc2c43)c(C(C)(C)c2ccccc2)c1 ; CC(C)(c1ccccc1)c1ccc(C(C)(C)c2ccccc2)c(N2c3ccccc3B3c4ccccc4N(c4ccccc4)c4cccc2c43)c1 ; CC(C)(c1ccccc1)c1cccc(C(C)(C)c2ccccc2)c1N1c2ccccc2B2c3ccccc3N(c3ccccc3)c3cccc1c32 ; CC(C)(c1ccccc1)c1ccccc1N1c2ccccc2B2c3ccccc3N(c3ccccc3)c3ccc(C(C)(C)c4ccccc4)c1c32]

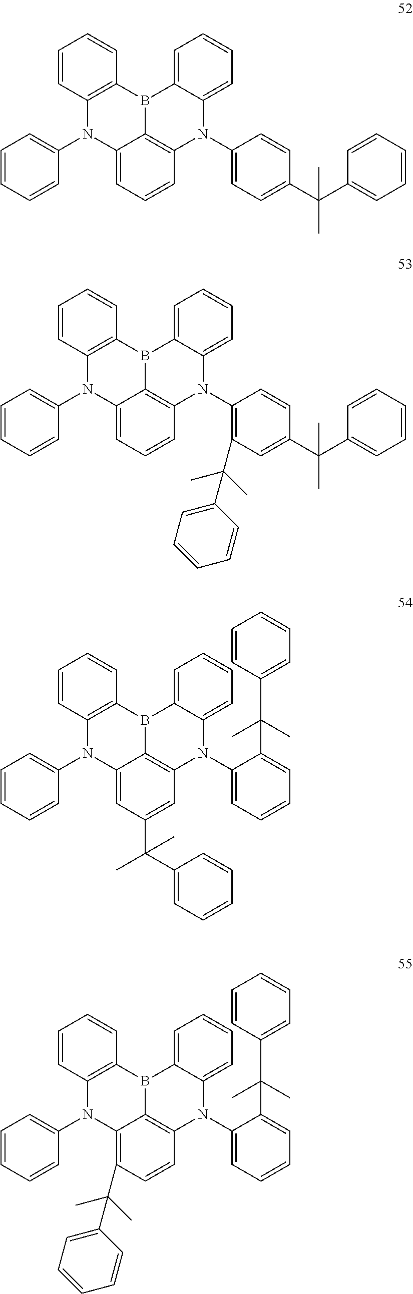 [SMILES: CC(C)(c1ccccc1)c1ccc(N2c3ccccc3B3c4ccccc4N(c4ccccc4)c4cccc2c43)cc1 ; CC(C)(c1ccccc1)c1ccc(N2c3ccccc3B3c4ccccc4N(c4ccccc4)c4cccc2c43)c(C(C)(C)c2ccccc2)c1 ; CC(C)(c1ccccc1)c1cc2c3c(c1)N(c1ccccc1C(C)(C)c1ccccc1)c1ccccc1B3c1ccccc1N2c1ccccc1 ; CC(C)(c1ccccc1)c1ccccc1N1c2ccccc2B2c3ccccc3N(c3ccccc3)c3c(C(C)(C)c4ccccc4)ccc1c32]

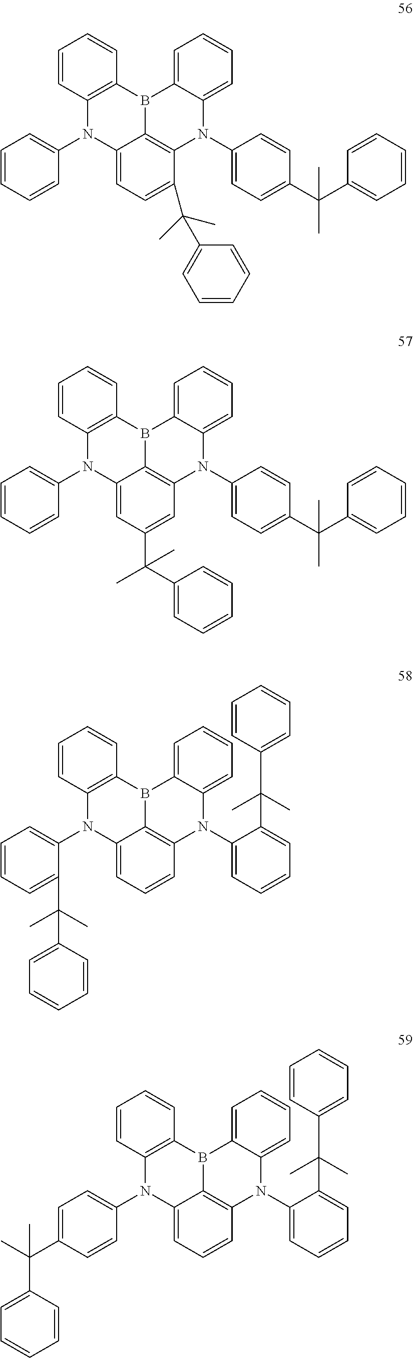 [SMILES: CC(C)(c1ccccc1)c1ccc(N2c3ccccc3B3c4ccccc4N(c4ccccc4)c4ccc(C(C)(C)c5ccccc5)c2c43)cc1 ; CC(C)(c1ccccc1)c1ccc(N2c3ccccc3B3c4ccccc4N(c4ccccc4)c4cc(C(C)(C)c5ccccc5)cc2c43)cc1 ; CC(C)(c1ccccc1)c1ccccc1N1c2ccccc2B2c3ccccc3N(c3ccccc3C(C)(C)c3ccccc3)c3cccc1c32 ; CC(C)(c1ccccc1)c1ccc(N2c3ccccc3B3c4ccccc4N(c4ccccc4C(C)(C)c4ccccc4)c4cccc2c43)cc1]

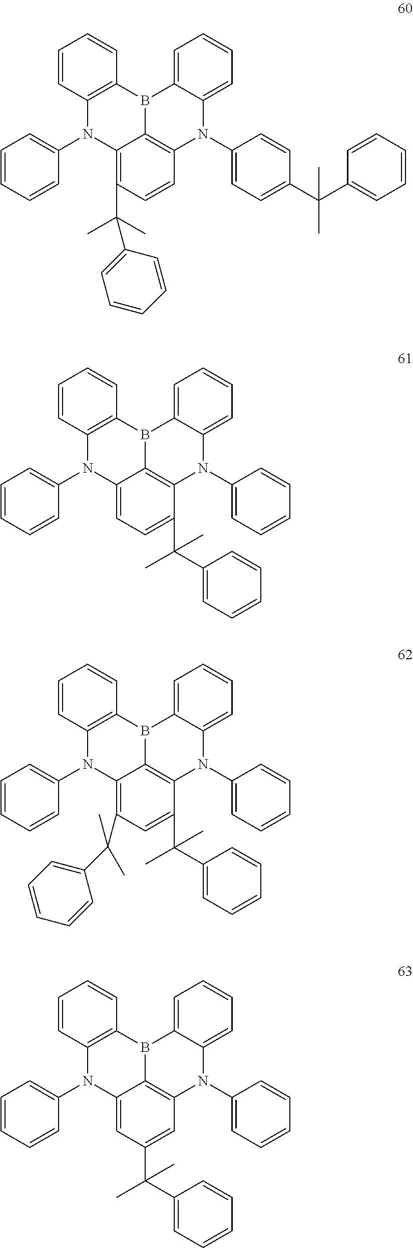 [SMILES: CC(C)(c1ccccc1)c1ccc(N2c3ccccc3B3c4ccccc4N(c4ccccc4)c4c(C(C)(C)c5ccccc5)ccc2c43)cc1 ; CC(C)(c1ccccc1)c1ccc2c3c1N(c1ccccc1)c1ccccc1B3c1ccccc1N2c1ccccc1 ; CC(C)(c1ccccc1)c1cc(C(C)(C)c2ccccc2)c2c3c1N(c1ccccc1)c1ccccc1B3c1ccccc1N2c1ccccc1 ; CC(C)(c1ccccc1)c1cc2c3c(c1)N(c1ccccc1)c1ccccc1B3c1ccccc1N2c1ccccc1]

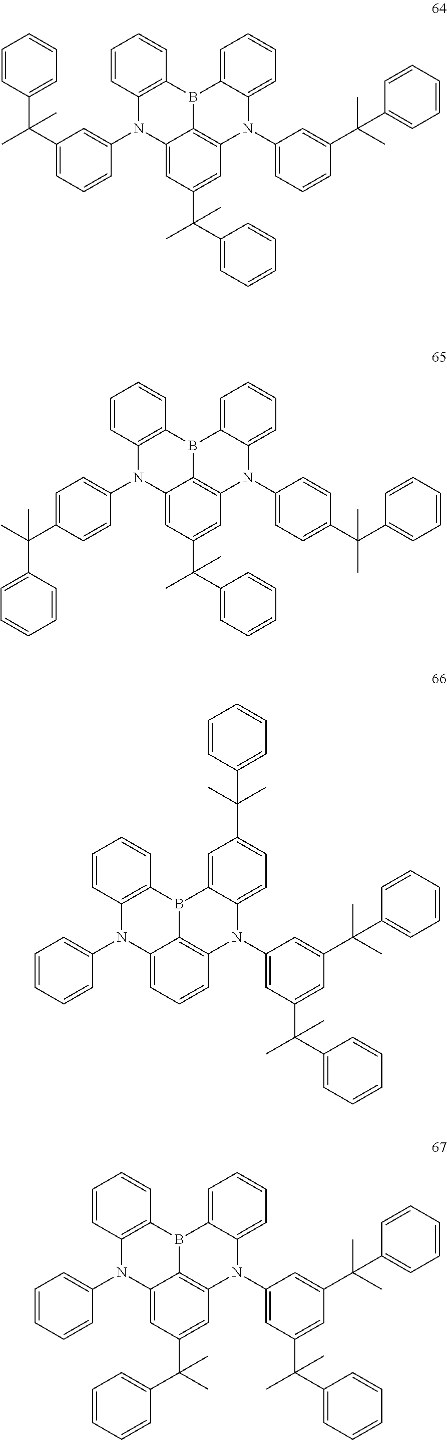 [SMILES: CC(C)(c1ccccc1)c1cccc(N2c3ccccc3B3c4ccccc4N(c4cccc(C(C)(C)c5ccccc5)c4)c4cc(C(C)(C)c5ccccc5)cc2c43)c1 ; CC(C)(c1ccccc1)c1ccc(N2c3ccccc3B3c4ccccc4N(c4ccc(C(C)(C)c5ccccc5)cc4)c4cc(C(C)(C)c5ccccc5)cc2c43)cc1 ; CC(C)(c1ccccc1)c1cc(N2c3ccc(C(C)(C)c4ccccc4)cc3B3c4ccccc4N(c4ccccc4)c4cccc2c43)cc(C(C)(C)c2ccccc2)c1 ; CC(C)(c1ccccc1)c1cc(N2c3ccccc3B3c4ccccc4N(c4ccccc4)c4cc(C(C)(C)c5ccccc5)cc2c43)cc(C(C)(C)c2ccccc2)c1]

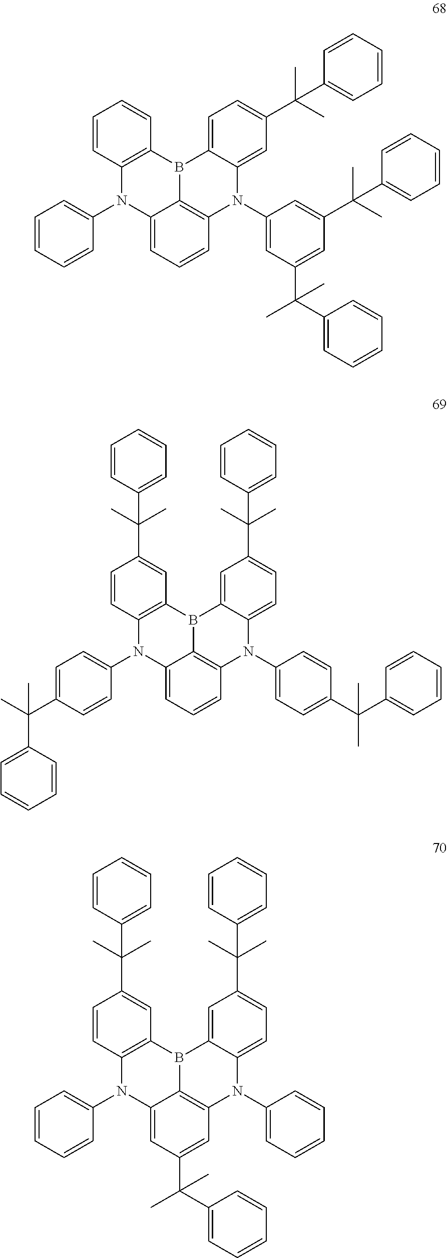 [SMILES: CC(C)(c1ccccc1)c1cc(N2c3cc(C(C)(C)c4ccccc4)ccc3B3c4ccccc4N(c4ccccc4)c4cccc2c43)cc(C(C)(C)c2ccccc2)c1 ; CC(C)(c1ccccc1)c1ccc(N2c3ccc(C(C)(C)c4ccccc4)cc3B3c4cc(C(C)(C)c5ccccc5)ccc4N(c4ccc(C(C)(C)c5ccccc5)cc4)c4cccc2c43)cc1 ; CC(C)(c1ccccc1)c1ccc2c(c1)B1c3cc(C(C)(C)c4ccccc4)ccc3N(c3ccccc3)c3cc(C(C)(C)c4ccccc4)cc(c31)N2c1ccccc1]

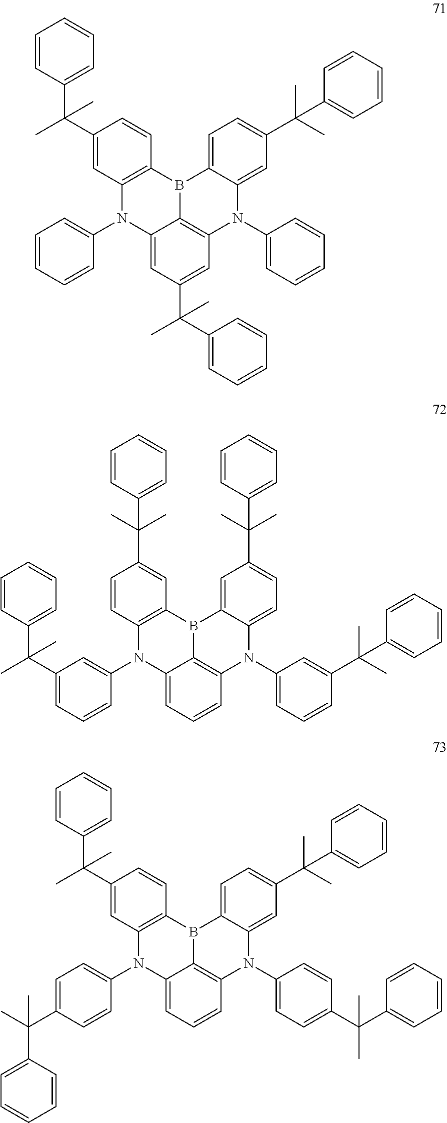 [SMILES: CC(C)(c1ccccc1)c1ccc2c(c1)N(c1ccccc1)c1cc(C(C)(C)c3ccccc3)cc3c1B2c1ccc(C(C)(C)c2ccccc2)cc1N3c1ccccc1 ; CC(C)(c1ccccc1)c1cccc(N2c3ccc(C(C)(C)c4ccccc4)cc3B3c4cc(C(C)(C)c5ccccc5)ccc4N(c4cccc(C(C)(C)c5ccccc5)c4)c4cccc2c43)c1 ; CC(C)(c1ccccc1)c1ccc(N2c3cc(C(C)(C)c4ccccc4)ccc3B3c4ccc(C(C)(C)c5ccccc5)cc4N(c4ccc(C(C)(C)c5ccccc5)cc4)c4cccc2c43)cc1]

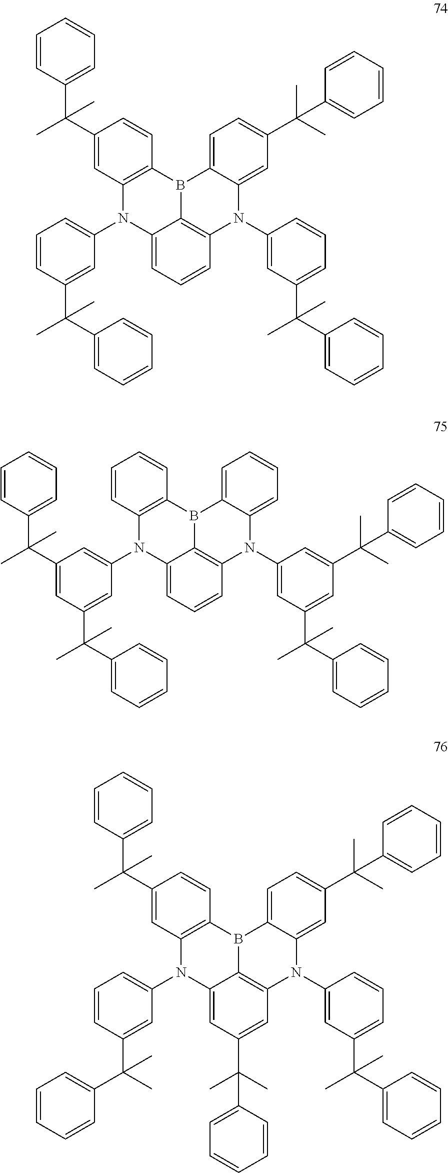

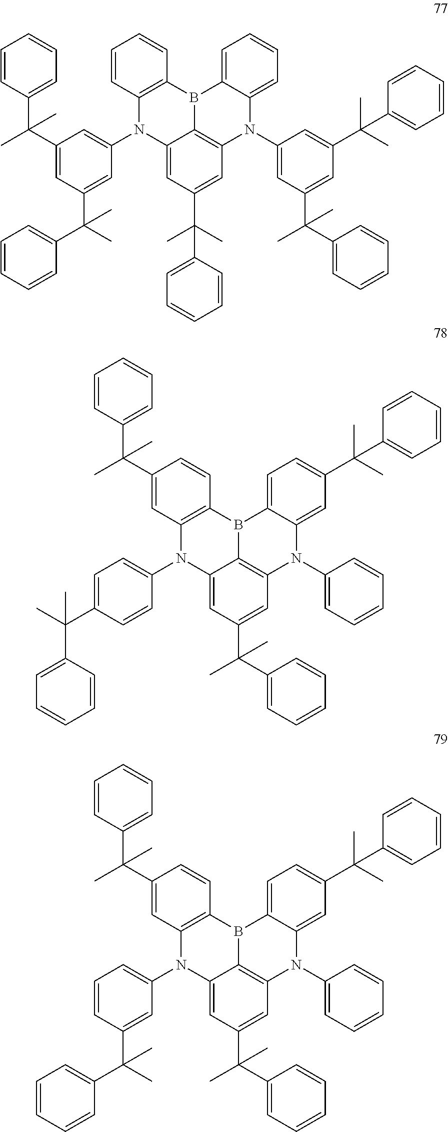

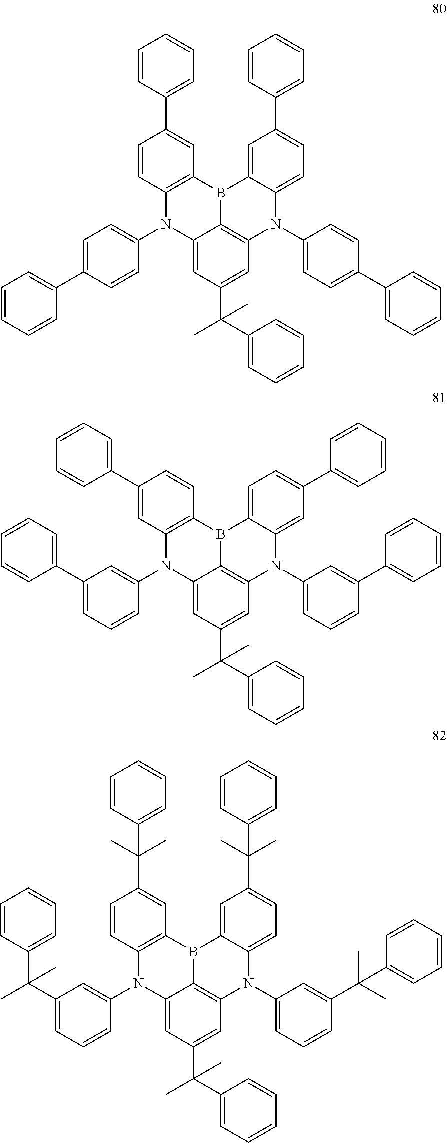

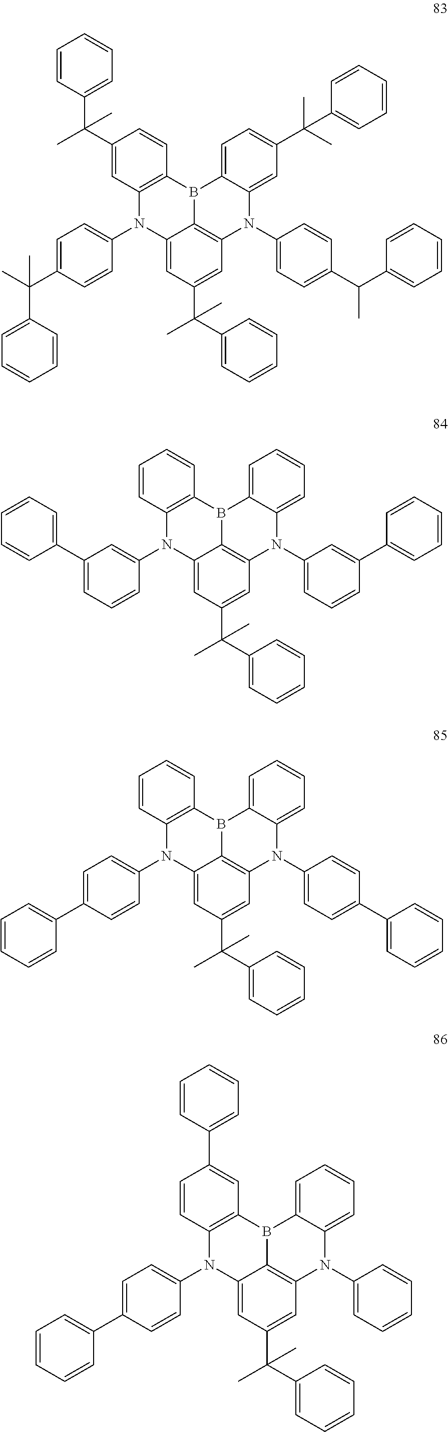

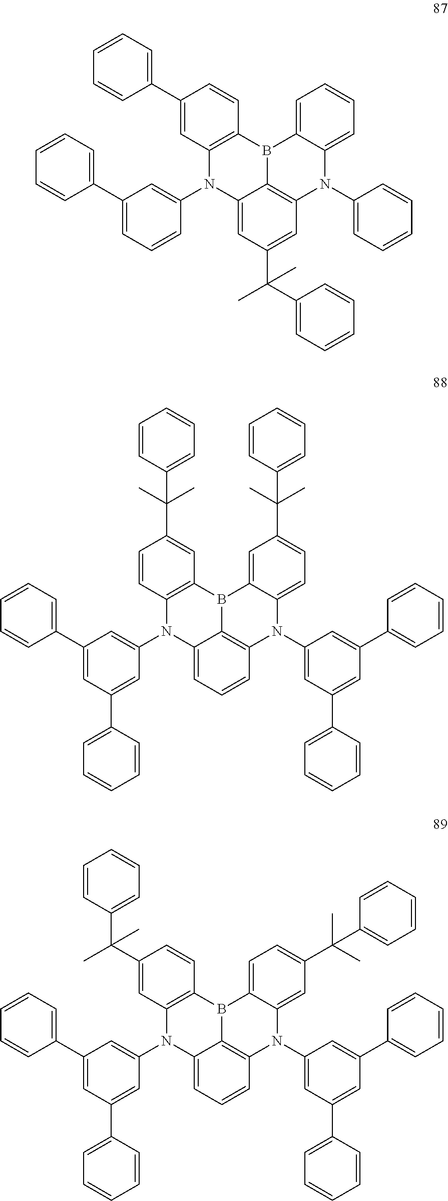

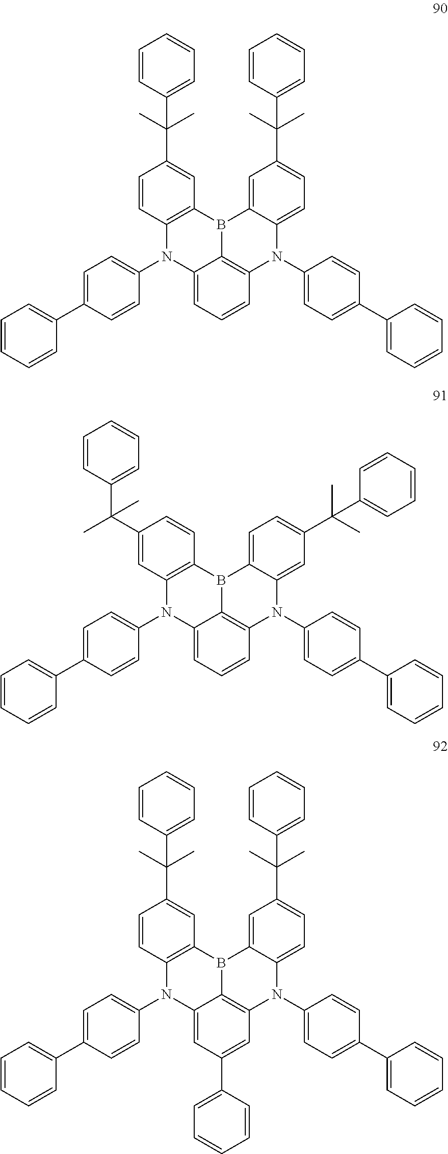

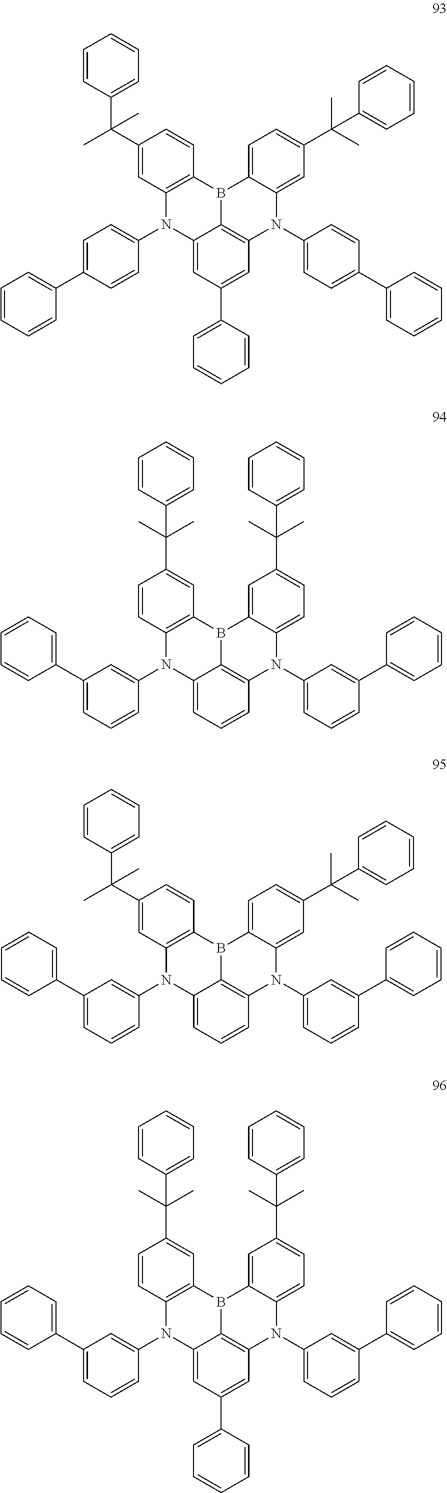 [SMILES: CC(C)(c1ccccc1)c1ccc2c(c1)N(c1ccc(-c3ccccc3)cc1)c1cc(-c3ccccc3)cc3c1B2c1ccc(C(C)(C)c2ccccc2)cc1N3c1ccc(-c2ccccc2)cc1 ; CC(C)(c1ccccc1)c1ccc2c(c1)B1c3cc(C(C)(C)c4ccccc4)ccc3N(c3cccc(-c4ccccc4)c3)c3cccc(c31)N2c1cccc(-c2ccccc2)c1 ; CC(C)(c1ccccc1)c1ccc2c(c1)N(c1cccc(-c3ccccc3)c1)c1cccc3c1B2c1ccc(C(C)(C)c2ccccc2)cc1N3c1cccc(-c2ccccc2)c1 ; CC(C)(c1ccccc1)c1ccc2c(c1)B1c3cc(C(C)(C)c4ccccc4)ccc3N(c3cccc(-c4ccccc4)c3)c3cc(-c4ccccc4)cc(c31)N2c1cccc(-c2ccccc2)c1]

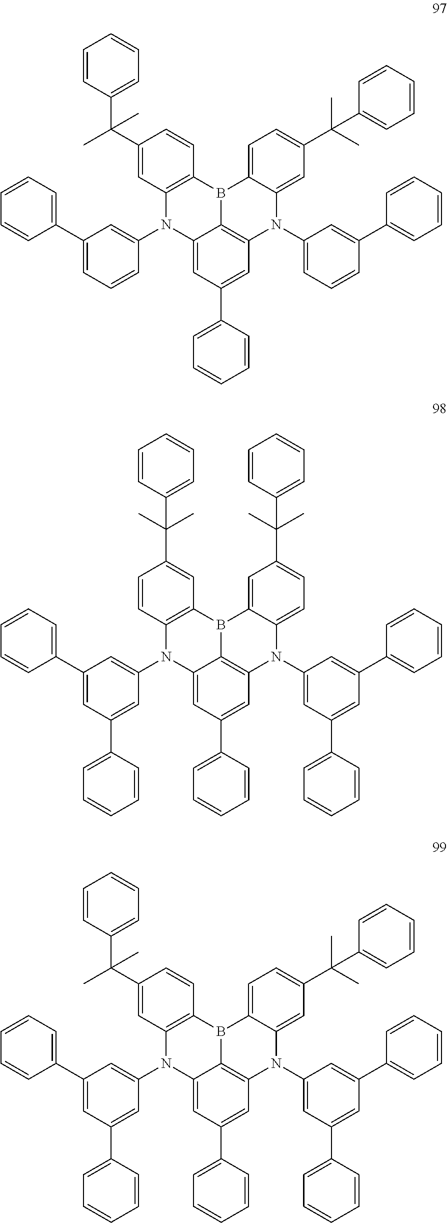 [SMILES: CC(C)(c1ccccc1)c1ccc2c(c1)N(c1cccc(-c3ccccc3)c1)c1cc(-c3ccccc3)cc3c1B2c1ccc(C(C)(C)c2ccccc2)cc1N3c1cccc(-c2ccccc2)c1 ; CC(C)(c1ccccc1)c1ccc2c(c1)B1c3cc(C(C)(C)c4ccccc4)ccc3N(c3cc(-c4ccccc4)cc(-c4ccccc4)c3)c3cc(-c4ccccc4)cc(c31)N2c1cc(-c2ccccc2)cc(-c2ccccc2)c1 ; CC(C)(c1ccccc1)c1ccc2c(c1)N(c1cc(-c3ccccc3)cc(-c3ccccc3)c1)c1cc(-c3ccccc3)cc3c1B2c1ccc(C(C)(C)c2ccccc2)cc1N3c1cc(-c2ccccc2)cc(-c2ccccc2)c1]

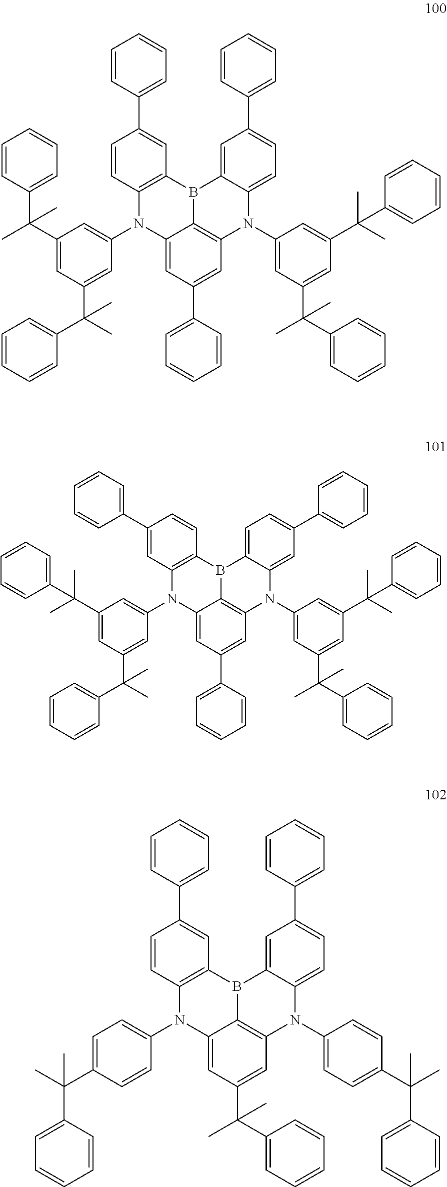 [SMILES: CC(C)(c1ccccc1)c1cc(N2c3ccc(-c4ccccc4)cc3B3c4cc(-c5ccccc5)ccc4N(c4cc(C(C)(C)c5ccccc5)cc(C(C)(C)c5ccccc5)c4)c4cc(-c5ccccc5)cc2c43)cc(C(C)(C)c2ccccc2)c1 ; CC(C)(c1ccccc1)c1cc(N2c3cc(-c4ccccc4)ccc3B3c4ccc(-c5ccccc5)cc4N(c4cc(C(C)(C)c5ccccc5)cc(C(C)(C)c5ccccc5)c4)c4cc(-c5ccccc5)cc2c43)cc(C(C)(C)c2ccccc2)c1 ; CC(C)(c1ccccc1)c1ccc(N2c3ccc(-c4ccccc4)cc3B3c4cc(-c5ccccc5)ccc4N(c4ccc(C(C)(C)c5ccccc5)cc4)c4cc(C(C)(C)c5ccccc5)cc2c43)cc1]

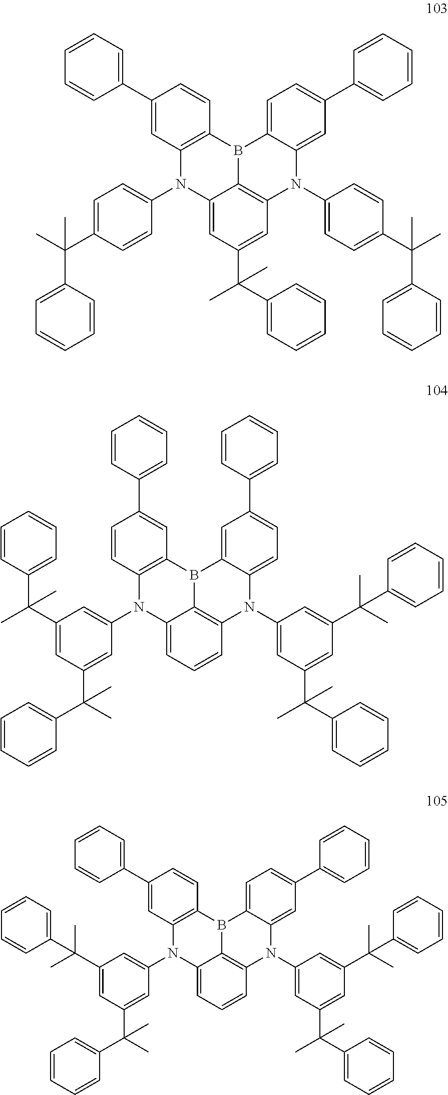 [SMILES: CC(C)(c1ccccc1)c1ccc(N2c3cc(-c4ccccc4)ccc3B3c4ccc(-c5ccccc5)cc4N(c4ccc(C(C)(C)c5ccccc5)cc4)c4cc(C(C)(C)c5ccccc5)cc2c43)cc1 ; CC(C)(c1ccccc1)c1cc(N2c3ccc(-c4ccccc4)cc3B3c4cc(-c5ccccc5)ccc4N(c4cc(C(C)(C)c5ccccc5)cc(C(C)(C)c5ccccc5)c4)c4cccc2c43)cc(C(C)(C)c2ccccc2)c1 ; CC(C)(c1ccccc1)c1cc(N2c3cc(-c4ccccc4)ccc3B3c4ccc(-c5ccccc5)cc4N(c4cc(C(C)(C)c5ccccc5)cc(C(C)(C)c5ccccc5)c4)c4cccc2c43)cc(C(C)(C)c2ccccc2)c1]

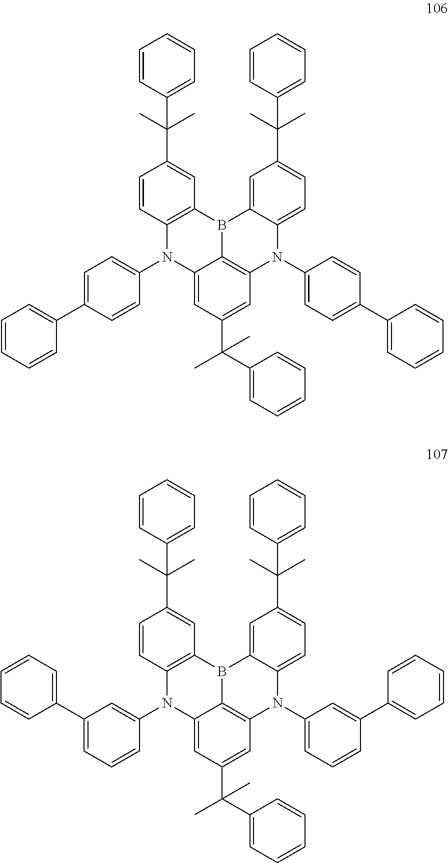 [SMILES: CC(C)(c1ccccc1)c1ccc2c(c1)B1c3cc(C(C)(C)c4ccccc4)ccc3N(c3ccc(-c4ccccc4)cc3)c3cc(C(C)(C)c4ccccc4)cc(c31)N2c1ccc(-c2ccccc2)cc1 ; CC(C)(c1ccccc1)c1ccc2c(c1)B1c3cc(C(C)(C)c4ccccc4)ccc3N(c3cccc(-c4ccccc4)c3)c3cc(C(C)(C)c4ccccc4)cc(c31)N2c1cccc(-c2ccccc2)c1]

17. An organic light-emitting device comprising:
a first electrode;
a second electrode; and
an organic layer comprising an emission layer,
wherein the organic layer is located between the first electrode and the second electrode, and
wherein the organic layer comprises at least one polycyclic compound of claim 1.

18. The organic light-emitting device of claim 17, wherein the emission layer comprises the polycyclic compound.

19. The organic light-emitting device of claim 18, wherein the emission layer further comprises:
a host; and
a sensitizer,
wherein the polycyclic compound is a light-emitting dopant, and
wherein an amount of the host in the emission layer is greater than a total combined amount of the light-emitting dopant and the sensitizer in the emission.

20. The organic light-emitting device of claim 19, wherein the host, the polycyclic compound, and the sensitizer each satisfy Equation 2:
[T₁(H)/S₁(H)]≥[T₁(S)/S₁(S)]≥[T₁(PC)/S₁(PC)] Equation 2
wherein, in Equation 2,
T₁(H) is a lowest excited triplet energy level of the host,
S₁(H) is a lowest excited singlet energy level of the host;
T₁(PC) is a lowest excited triplet energy level of the polycyclic compound;
S₁(PC) is a lowest excited singlet energy level of the polycyclic compound;
T₁(S) is a lowest excited triplet energy level of the sensitizer; and
S₁(S) is a lowest excited singlet energy level of the sensitizer.
